(19) United States
(12) Patent Application Publication
(10) Pub. No.: US 2026/0371831 A1
(43) Pub. Date: Nov. 19, 2026

(54) LIGHT EMITTING ELEMENT, FUSED POLYCYCLIC COMPOUND FOR THE LIGHT EMITTING ELEMENT, AND ELECTRONIC APPARATUS INCLUDING THE LIGHT EMITTING ELEMENT

(71) Applicant: Samsung Display Co., Ltd., Yongin-si (KR)

(72) Inventors: Hirokazu KUWABARA, Yokohama (JP); Keigo HOSHI, Yokohama (JP); Yoshiro SUGITA, Yokohama (JP)

(21) Appl. No.: 19/555,737

(22) Filed: Mar. 3, 2026

(30) Foreign Application Priority Data
Apr. 21, 2025 (JP) 2025-069307

(51) Int. Cl. H10K 50/11; H10K 85/30; H10K 85/40; H10K 85/60

(52) U.S. Cl. CPC H10K 50/11; H10K 85/342; H10K 85/346; H10K 85/40; H10K 85/623; H10K 85/626; H10K 85/633; H10K 85/636; H10K 85/654; H10K 85/6572; H10K 85/6574; H10K 85/6576; H10K 85/658

(57) ABSTRACT

A light emitting element includes a first electrode, a second electrode on the first electrode, and an emission layer between the first electrode and the second electrode, where the emission layer includes a first compound represented by Formula 1.

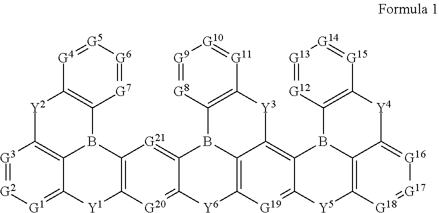

### CROSS-REFERENCE TO RELATED APPLICATION

The present application claims priority to and the benefit of Japanese Patent Application No. 2025-069307, filed on Apr. 21, 2025, in the Japan Patent Office, the entire content of which is incorporated herein by reference.

### BACKGROUND

### 1. Field

One or more embodiments of the present disclosure relate to a light emitting element, a fused polycyclic compound used in the light emitting element, and an electronic apparatus including the light emitting element.

### 2. Description of the Related Art

As image display devices, organic electroluminescence display devices and/or the like have seen active development in recent years. The organic electroluminescence display devices and/or the like are display devices including self-luminescent light emitting elements in which holes and electrons respectively injected from a first electrode and a second electrode under a driving voltage recombine in an emission layer. As a result, a luminescent material in the emission layer emits light to accomplish display of images.

When applying light emitting elements to display devices, improvements in element lifespan are desired or required, and thus there is a continuous demand or desire for the development of materials, for light emitting elements, that may stably achieve such improvements.

### SUMMARY

One or more aspects of embodiments of the present disclosure are directed toward a light emitting element that has improved lifespan, and an electronic apparatus including the same.

One or more aspects of embodiments of the present disclosure are directed toward a fused polycyclic compound as a material for a light emitting element, which improves lifespan of the light emitting element.

Additional aspects will be set forth in part in the description which follows and, in part, will be apparent from the description, or may be learned by practice of the presented embodiments.

According to one or more embodiments of the present disclosure, a light emitting element includes a first electrode, a second electrode on (e.g., arranged on) the first electrode, and an emission layer between (e.g., arranged between) the first electrode and the second electrode and including a first compound represented by Formula 1.

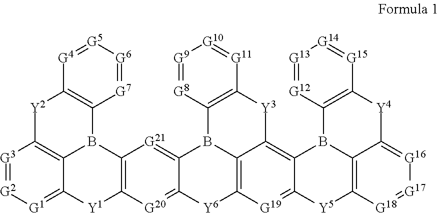

In Formula 1, Y¹ to Y⁶ may each independently be O, S, or NR^{y}, at least one selected from among G¹ to G²¹ may be CR^{x1}, and the others may each independently be N or CR^{x2}, R^{x1} may be deuterium, a halogen atom, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, R^{x2} and R^{y} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, if (e.g., when) G² is CR^{x1} or CR^{x2}, R^{x1} and R^{x2} may not be substituted or unsubstituted amine groups, if (e.g., when) G¹⁷ is CR^{x1} or CR^{x2}, R^{x1} and R^{x2} may not be substituted or unsubstituted amine groups, and the first compound may include a chemical structure in which any hydrogen in molecules thereof may optionally be substituted with deuterium (e.g., one or more hydrogens of the first compound are optionally substituted with deuterium).

In one or more embodiments, the emission layer may further include at least one of a second compound represented by Formula HT-1, a third compound represented by Formula ET-1, or a fourth compound represented by Formula D-1.

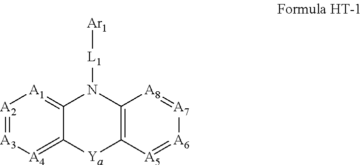

In Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR54R₅₅, Ar₁ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

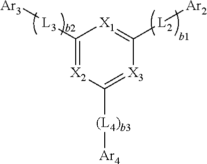

In Formula ET-1, at least one selected from among X₁ to X₃ may be N and the others are CR₅₆, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

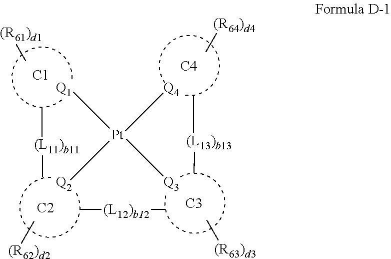

In Formula D-1, Q₁ to Q₄ may each independently be C or N, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, L₁₁ to L₁₃ may each independently be a direct linkage, *—O—*, *—S—*,

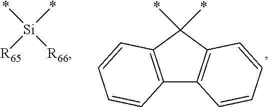

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the first compound represented by Formula 1 may be represented by any one selected from among Formulas 1-A1 to 1-A8.

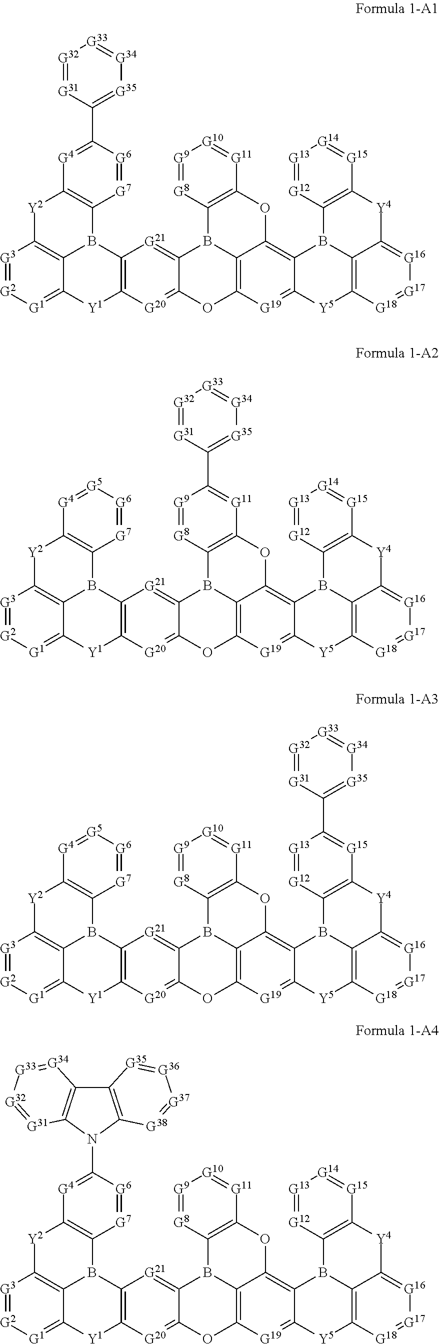

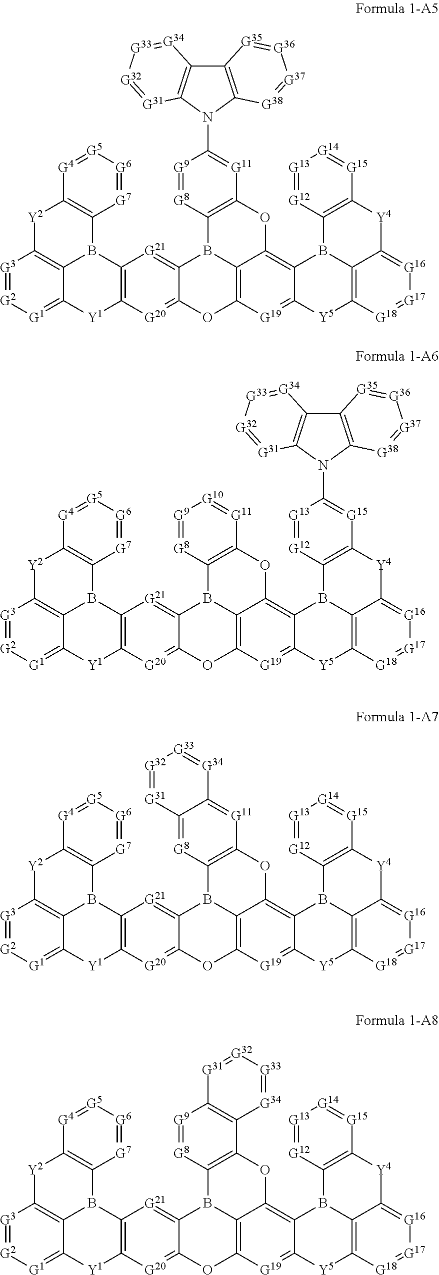

In Formulas 1-A1 to 1-A8, G³¹ to G³⁸ may each independently be N or CR^{X3}, R^{X3} may be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and Y¹, Y², Y⁴, Y⁵, and G¹ to G²¹ may each be the same as defined in Formula 1.

In one or more embodiments, the first compound represented by Formula may be represented by any one selected from among Formulas 1-B1 to 1-B4.

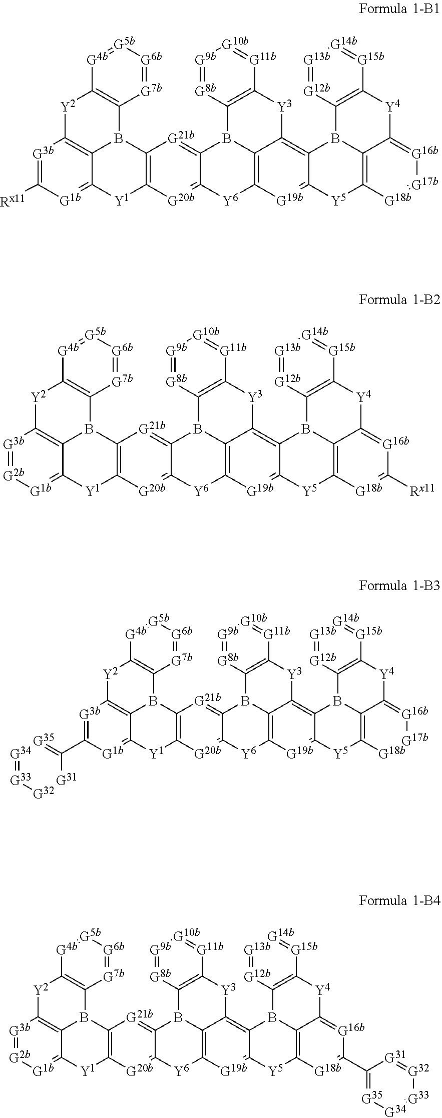

In Formulas 1-B1 to 1-B4, G^{1b} to G²¹b and G³¹ to G³⁵ may each independently be N or CR^{x2}, R^{x11} may be a substituted or unsubstituted alkyl group having 1 to 20 carbon atoms, and Y¹ to Y⁶ and R^{x2} may each be the same as defined in Formula 1.

In one or more embodiments, the first compound represented by Formula 1 may be represented by Formula 2.

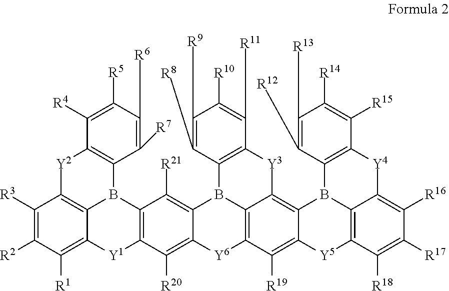

In Formula 2, R¹ to R²¹ may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, at least one selected from among R¹ to R²¹ may not be hydrogen, R² and R¹⁷ may not each be a substituted or unsubstituted amine group, and Y¹ to Y⁶ may each be the same as defined in Formula 1.

In one or more embodiments, the first compound represented by Formula 2 may be represented by any one selected from among Formulas 2-A1 to 2-A5 and Formulas 2-B1 to 2-B10.

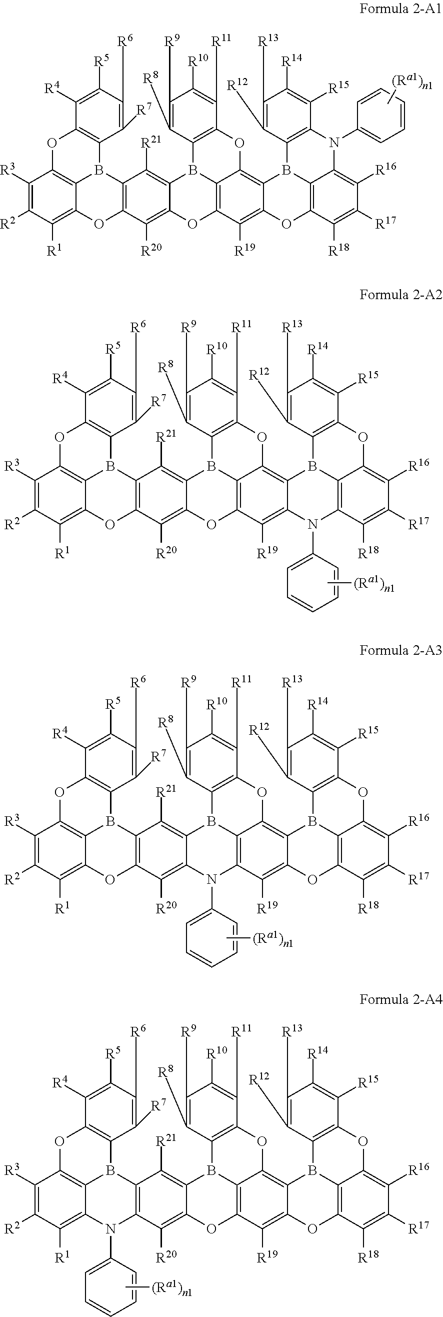

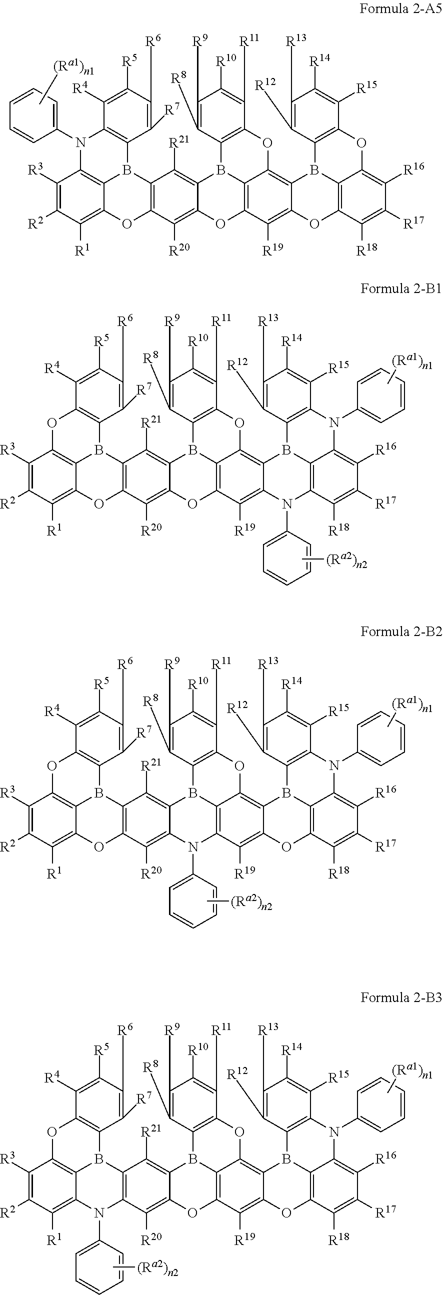

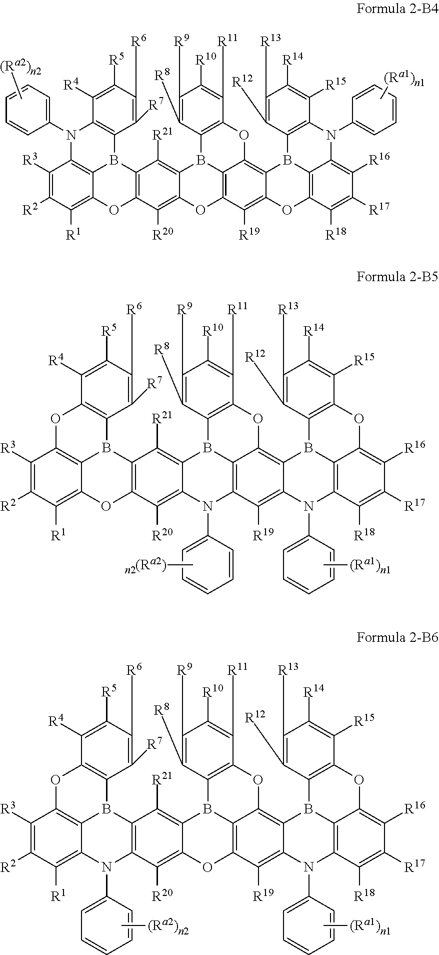

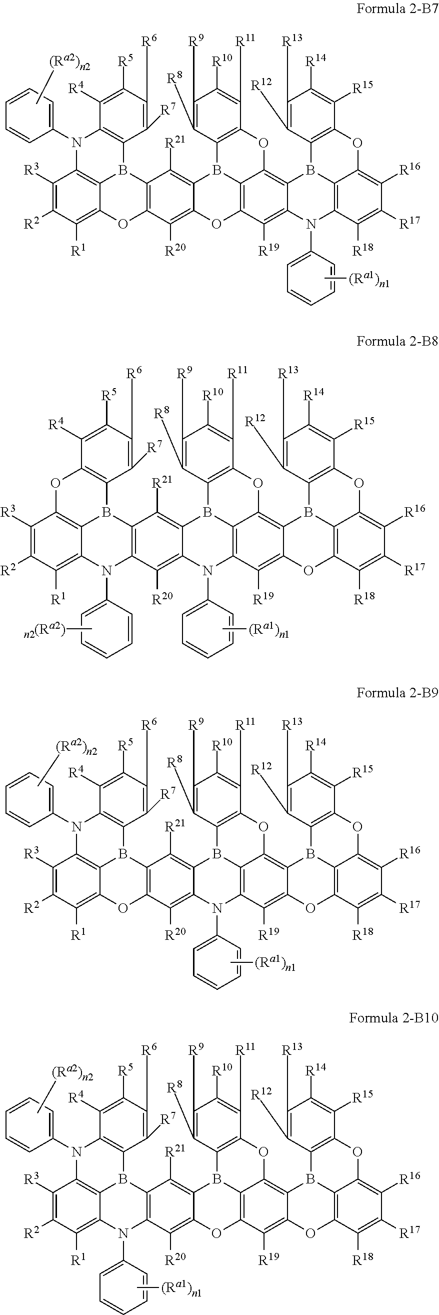

In Formulas 2-A1 to 2-A5 and Formulas 2-B1 to 2-B10, n1 and n2 may each independently be an integer of 0 to 5, R^{a1} and R^{a2} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and R¹ to R²¹ may each be the same as defined in Formula 2.

In one or more embodiments, the first compound represented by Formula 2 may be represented by any one selected from among Formulas 2-C1 to 2-C10 and Formulas 2-D1 to 2-D5.

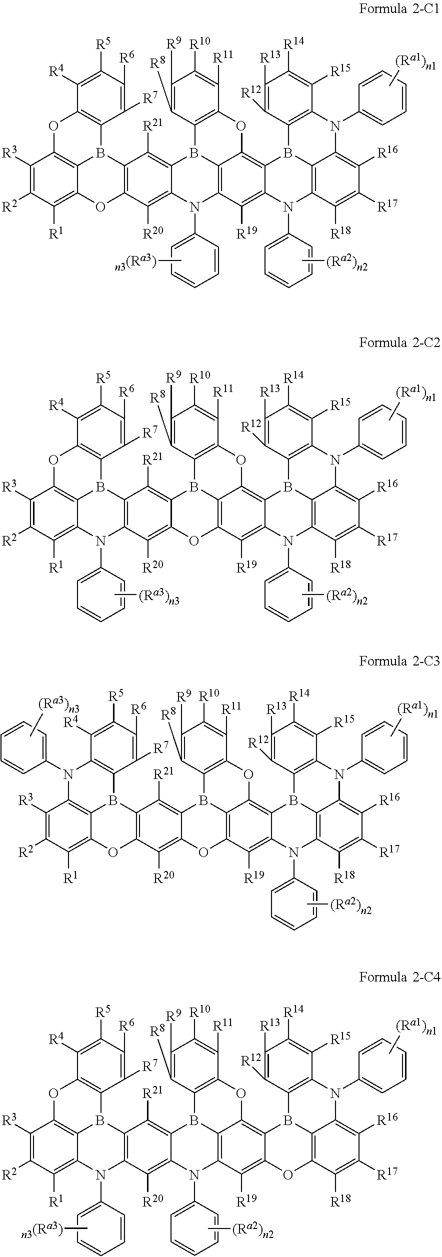

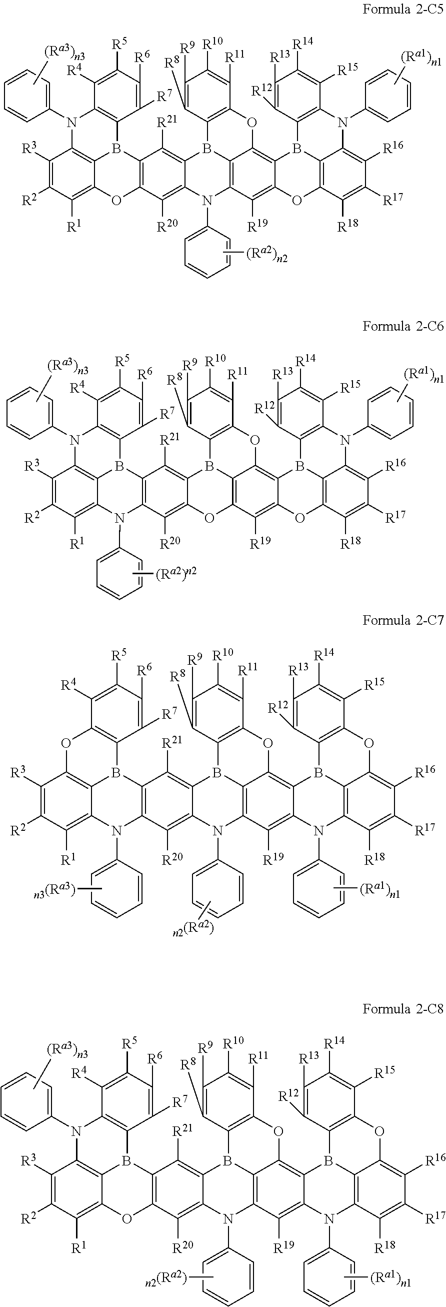

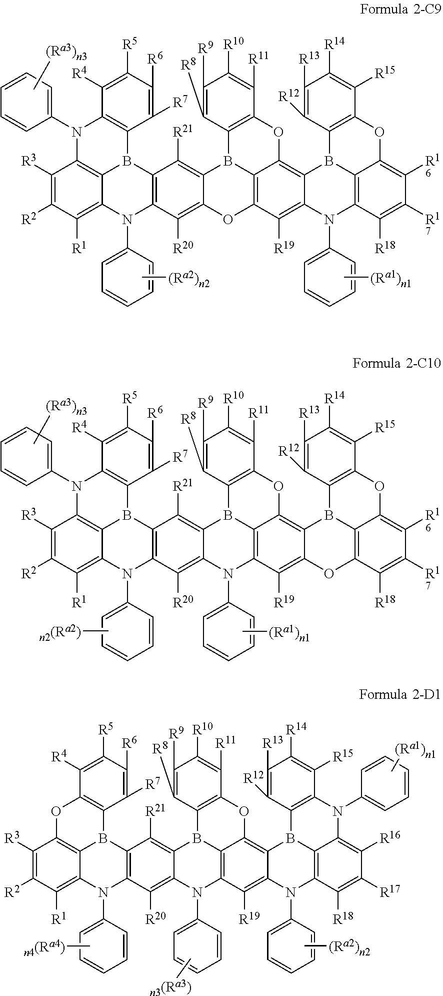

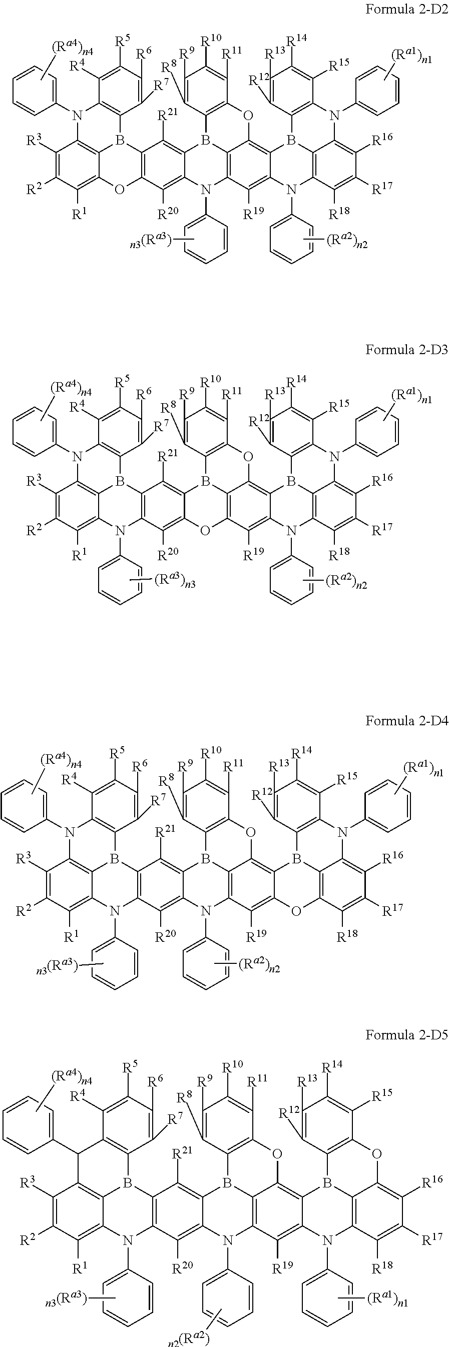

In Formulas 2-C1 to 2-C10 and Formulas 2-D1 to 2-D5, n1 to n4 may each independently be an integer of 0 to 5, R^{a1} to R^{a4} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and R¹ to R²¹ may each be the same as defined in Formula 2.

In one or more embodiments, in Formula 2, at least one selected from among R¹ to R²¹ may be a substituted or unsubstituted t-butyl group, a substituted or unsubstituted phenyl group, or a substituted or unsubstituted carbazole group.

In one or more embodiments, in Formula 2, at least one selected from among R¹ to R²¹ may be represented by any one selected from among R-1 to R-7.

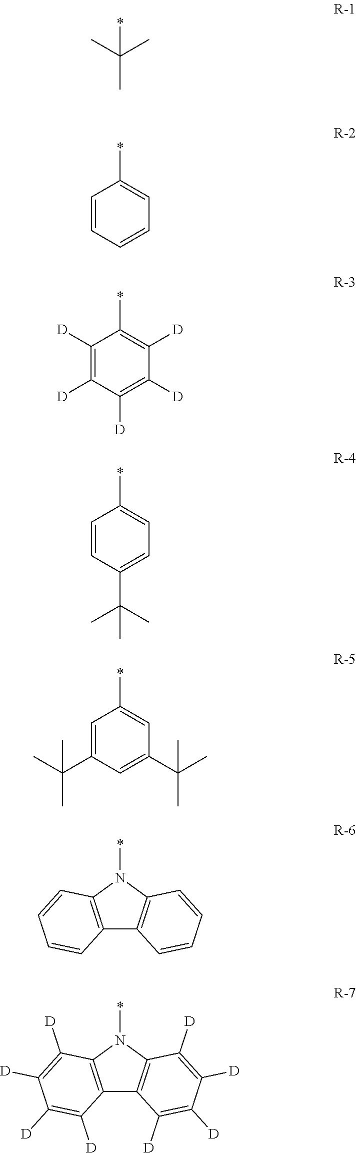

In R-3 and R-7, D is deuterium.

In one or more embodiments of the present disclosure, provided is a fused polycyclic compound represented by Formula 1.

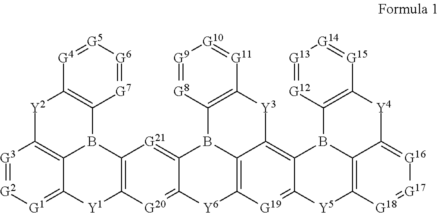

In Formula 1, Y¹ to Y⁶ may each independently be O, S, or NR^{y}, at least one selected from among G¹ to G²¹ may be CR^{x1}, and the others may each independently be N or CR^{x2}, R^{x1} may be deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, R^{x2} and R^{y} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, if (e.g., when) G² is CR^{x1} or CR^{x2}, R^{x1} and R^{x2} may not be substituted or unsubstituted amine groups, if (e.g., when) G¹⁷ is CR^{x1} or CR^{x2}, R^{x1} and R^{x2} may not be substituted or unsubstituted amine groups, and the fused polycyclic compound may include a chemical structure in which any hydrogen in molecule thereof may optionally be substituted with deuterium (e.g., one or more hydrogens of the fused polycyclic compound are optionally substituted with deuterium).

According to one or more embodiments of the disclosure, an electronic apparatus includes a base layer, a circuit layer on (e.g., arranged on) the base layer, and a display element layer on (e.g., arranged on) the circuit layer and including a light emitting element, wherein the light emitting element includes a first electrode, a second electrode on (e.g., arranged on) the first electrode, and an emission layer between (e.g., arranged between) the first electrode and the second electrode and containing a fused polycyclic compound represented by Formula 1.

In one or more embodiments, the electronic apparatus may further include at least one of a processor, a power module, or a memory.

### BRIEF DESCRIPTION OF THE DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a plan view showing a display device according to one or more embodiments of the present disclosure;

FIG. 2 is a cross-sectional view showing a portion corresponding to the line I-I′ of FIG. 1 according to one or more embodiments of the present disclosure;

FIG. 3 is a cross-sectional view schematically showing a light emitting element according to one or more embodiments of the present disclosure;

FIG. 4 is a cross-sectional view schematically showing a light emitting element according to one or more embodiments of the present disclosure;

FIG. 5 is a cross-sectional view schematically showing a light emitting element according to one or more embodiments of the present disclosure;

FIG. 6 is a cross-sectional view schematically showing a light emitting element according to one or more embodiments of the present disclosure;

FIG. 7A is an image showing lowest unoccupied molecular orbital (LUMO) distribution of a fused polycyclic compound according to one or more embodiments of the present disclosure;

FIG. 7B is an image showing highest occupied molecular orbital (HOMO) distribution of a fused polycyclic compound according to one or more embodiments of the present disclosure;

FIG. 7C is an image showing LUMO orbital distribution of a fused polycyclic compound according to one or more embodiments of the present disclosure;

FIG. 7D is an image showing HOMO orbital distribution of a fused polycyclic compound according to one or more embodiments of the present disclosure;

FIG. 8 is a cross-sectional view showing a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure;

FIG. 11 is a cross-sectional view showing a display device according to one or more embodiments of the present disclosure;

FIG. 12 is a view showing an interior of a vehicle in which a display device according to one or more embodiments of the present disclosure is arranged;

FIG. 13 is a perspective view showing an electronic apparatus according to one or more embodiments of the present disclosure;

FIG. 14 is an exploded perspective view showing an electronic apparatus according to one or more embodiments of the present disclosure;

FIG. 15 is a block diagram of an electronic apparatus according to one or more embodiments of the present disclosure; and

FIG. 16 shows schematic views of various electronic apparatuses according to one or more embodiments of the present disclosure.

### DETAILED DESCRIPTION

The accompanying drawings are included to provide a further understanding of the present disclosure, and are incorporated in and constitute a part of this disclosure. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

In this disclosure, it will be understood that if (e.g., when) an element (or a region, a layer, a portion, and/or the like) is referred to as being “on”, “connected to” or “coupled to” another element, it may be directly arranged on, connected or coupled to the other element, or one or more intervening elements may be arranged therebetween. In contrast, “directly on” may refer to that there are no additional layers, films, regions, plates, and/or the like, between the element and the other element. For example, “directly on” or “directly under” may refer to two layers or two members are arranged without utilizing an additional member such as an adhesive member therebetween.

In the present disclosure, like reference numerals or symbols refer to like elements throughout, and duplicative descriptions thereof may not be provided for conciseness. In the drawings, the thickness, the ratio, and/or the size of an element may be exaggerated or reduced for effective description of the technical contents. As used herein, the term “and/or” or “or” or “/” may include any and all combinations of one or more of the associated listed items.

It will be understood that, although the terms “first,” “second,” and/or the like may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed herein could be termed a second element, component, region, layer, or section without departing from the scope and teaching of the disclosure. Similarly, a second element, component, region, layer, or section may be termed a first element, component, region, layer, or section. As used herein, the singular forms, “a”, “an”, “one”, and “the” are intended to include the plural forms as well, unless the context clearly indicates otherwise. Further, the utilization of “may” when describing embodiments of the present disclosure refers to “one or more embodiments of the present disclosure”.

Also, the terms “below”, “on lower side”, “above”, “on upper side”, and/or the like may be used to describe the relationships of elements illustrated in the drawings. These terms have relative concepts and are described on the basis of the directions indicated in the drawings.

It will be further understood that the terms “comprise(s)/comprising”, “include(s)/including”, and/or “has(have)/having”, if (e.g., when) used in this disclosure, specify the presence of stated features, numbers, steps, operations, elements, components, and/or groups thereof, but do not preclude the presence or addition of one or more other features, numbers, steps, operations, elements, components, and/or groups thereof. Additionally, the terms “comprise(s)/comprising,” “include(s)/including,” “has(have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the disclosure, the term “substituted or unsubstituted” may refer to substituted or unsubstituted with at least one substituent selected from the group consisting of deuterium, a halogen, a cyano group, a nitro group, an amine group, an amino group, a silyl group, an oxy group, a thio group, a sulfinyl group, a sulfonyl group, a carbonyl group, a boron group, a selenium group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In one or more embodiments, the ring formed by adjacent groups being bonded to each other may be connected to another ring to form a spiro structure.

In the disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the disclosure, examples of a halogen may include fluorine, chlorine, bromine, or iodine.

In the disclosure, an alkyl group may be linear or branched. The number of carbons in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the disclosure, a cycloalkyl group may refer to a cyclic alkyl group. The number of carbons in the cycloalkyl group may be 3 to 60, 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, and/or the like, but embodiments of the present disclosure are not limited thereto.

In the disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but are not limited thereto.

In the disclosure, a hydrocarbon ring group refers to any functional group or substituent derived from an aliphatic hydrocarbon ring. The number of ring-forming carbon atoms in the hydrocarbon ring group may be 5 to 60, 5 to 30, or 5 to 20.

In the disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the disclosure, a fluorenyl group may be substituted, and two substituents may be bonded to each other to form a spiro structure. Examples of the substituted fluorenyl group are as follows. However, embodiments of the present disclosure are not limited thereto.

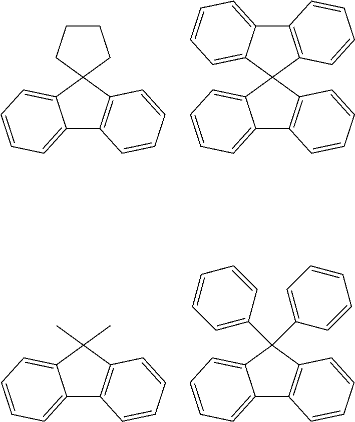

The term “heterocyclic group” as used herein refers to any functional group or substituent derived from a ring containing at least one of B, O, N, P, Si, S, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may each be monocyclic or polycyclic.

In the disclosure, the heterocyclic group may contain at least one of B, O, N, P, Si, S or Se as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the disclosure, an aliphatic heterocyclic group may include at least one of B, O, N, P, Si, S, or Se as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the disclosure, a heteroaryl group may contain at least one of B, O, N, P, Si, S, or Se as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the disclosure, the above description of the aryl group may be applied to an arylene group except that the arylene group is a divalent group. The above description of the heteroaryl group may be applied to a heteroarylene group except that the heteroarylene group is a divalent group.

In the disclosure, a silyl group includes an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the disclosure, the number of carbon atoms in a carbonyl group is not specifically limited, for example, may be 1 to 40, 1 to 30, or 1 to 20. For example, the carbonyl group may have the following structures, but the embodiments of the present disclosure are not limited thereto.

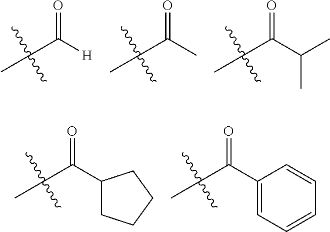

In the disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but embodiments of the present disclosure are not limited thereto.

In the disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring chain. The number of carbon atoms in the alkoxy group is not specifically limited, for example, may be 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

The term “boron group” as used herein may refer to that a boron atom is bonded to the alkyl group or the aryl group defined above. The boron group includes an alkyl boron group and/or an aryl boron group. Examples of the boron group may include a dimethylboron group, a diethylboron group, a t-butylmethylboron group, a diphenylboron group, a phenylboron group, and/or the like, but embodiments of the present disclosure are not limited thereto.

In the disclosure, the number of carbon atoms in an amine group is not specifically limited, for example, may be 1 to 50, 1 to 30, or 1 to 20. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto. In one or more embodiments, the term “amine group” may be used interchangeable with “amino group.”

In the disclosure, a selenium (Se) group may include an alkyl selenium group and/or an aryl selenium group. The selenium group may refer to a group in which a selenium atom is bonded to the above-defined alkyl group or aryl group. Examples of the selenium group may include a methyl selenium group, an ethyl selenium group, a propyl selenium group, a pentyl selenium group, a hexyl selenium group, an octyl selenium group, a dodecyl selenium group, a cyclopentyl selenium group, a cyclohexyl selenium group, a phenyl selenium group, a naphthyl selenium group, and/or the like. However, embodiments of the present disclosure are not limited thereto.

In the disclosure, the alkyl group among an alkylthio group, an alkylsulfoxy group, an alkylaryl group, an alkylamino group, an alkyl boron group, an alkyl silyl group, an alkyl amine group, and an alkyl selenium group is the same as examples of the alkyl group described above.

In the disclosure, the aryl group among an aryloxy group, an arylthio group, an arylsulfoxy group, an arylamino group, an arylboron group, an arylsilyl group, an arylamine group, and an aryl selenium group is the same as examples of the aryl group described above.

In the disclosure, a direct linkage may refer to a single bond. In the disclosure,

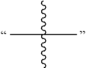

and “—*” each refer to a position to be connected.

Hereinafter, embodiments of the present disclosure will be described in more detail with reference to the accompanying drawings.

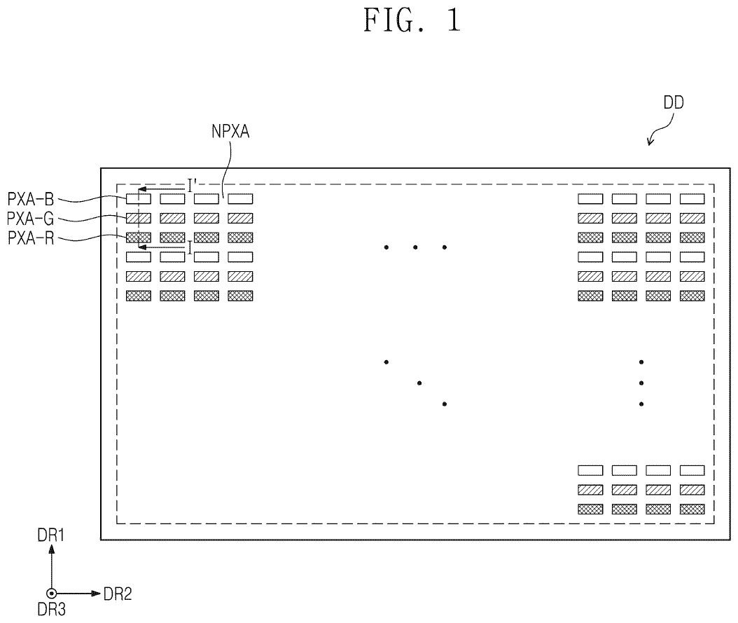

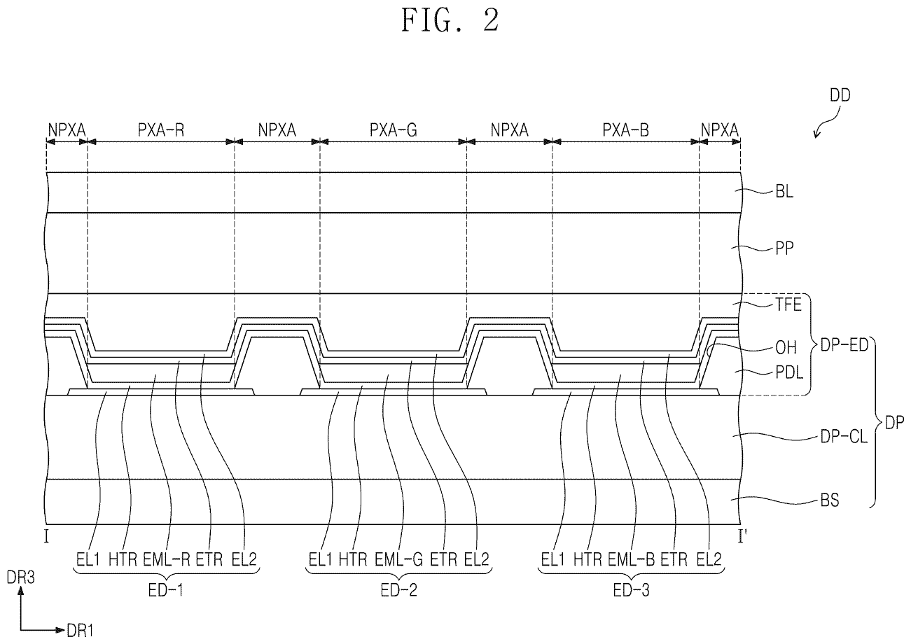

FIG. 1 is a plan view illustrating a display device DD according to one or more embodiments of present disclosure. FIG. 2 is a cross-sectional view of the display device DD according to one or more embodiments. For example, FIG. 2 is a cross-sectional view illustrating a part taken along the line I-I′ of FIG. 1.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 respectively arranged between portions of the pixel defining film PDL, and an encapsulation layer TFE arranged on the light emitting elements ED-1, ED-2, and ED-3.

The base layer BS may be a member which provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL is arranged on the base layer BS, and the circuit layer DP-CL may include a plurality of transistors. Each of the transistors may include a control electrode, an input electrode, and an output electrode. For example, in one or more embodiments, the circuit layer DP-CL may include switching transistor(s) and driving transistor(s) for driving the light emitting elements ED-1, ED-2, and ED-3 of the display element layer DP-ED.

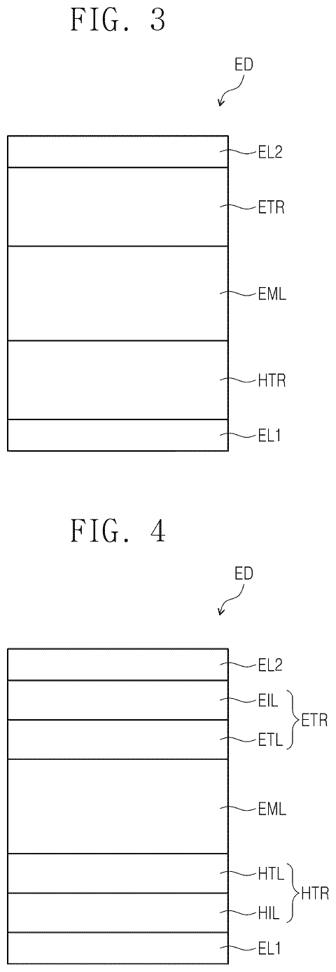

Each of the light emitting elements ED-1, ED-2, and ED-3 may independently have a structure of a light emitting element ED of embodiments according to FIGS. 3 to 6, which will be described later. Each of the light emitting elements ED-1, ED-2, and ED-3 may include a first electrode EL1, a hole transport region HTR, respective emission layer EML-R, EML-G, or EML-B, an electron transport region ETR, and a second electrode EL2.

FIG. 2 illustrates an embodiment in which the respective emission layers EML-R, EML-G, and EML-B of the light emitting elements ED-1, ED-2, and ED-3 are each separately arranged in openings OH defined in the pixel defining film PDL, and the hole transport region HTR, the electron transport region ETR, and the second electrode EL2 are each provided as a common layer for the entire light emitting elements ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel defining film PDL. For example, in one or more embodiments, the hole transport region HTR, the respective emission layers EML-R, EML-G, and EML-B, and the electron transport region ETR of the light emitting elements ED-1, ED-2, and ED-3 may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. In one or more embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from one another on a plane.

Each of the light emitting regions PXA-R, PXA-G, and PXA-B may be a region divided by the pixel defining film PDL. The non-light emitting region NPXA may be areas between adjacent light emitting regions PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective emission layers EML-R, EML-G, and EML-B of the light emitting elements ED-1, ED-2, and ED-3 may be arranged in opening OH defined in the pixel defining film PDL and separated from one another.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIG. 1 and FIG. 2, three light emitting regions PXA-R, PXA-G, and PXA-B, which emit red color light, green color light, and blue color light, respectively, are illustrated as an example. For example, the display device DD of one or more embodiments may include the red light emitting region PXA-R, the green light emitting region PXA-G, and the blue light emitting region PXA-B that are separated from one another.

In the display device DD according to one or more embodiments, the plurality of light emitting elements ED-1, ED-2, and ED-3 may be to emit light beams having wavelengths different from one another. For example, in one or more embodiments, the display device DD may include a first light emitting element ED-1 that emits red color light, a second light emitting element ED-2 that emits green color light, and a third light emitting element ED-3 that emits blue color light. For example, in one or more embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range, or at least one light emitting element may be to emit a light beam in a wavelength range different from the others. For example, in one or more embodiments, the first to third light emitting elements ED-1, ED-2, and ED-3 may all emit blue color light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second direction axis DR2, the plurality of green light emitting regions PXA-G may be arranged with each other along the second direction axis DR2, and the plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from one another according to the wavelength range of the emitted light. In this regard, the areas of the light emitting regions PXA-R, PXA-G, and PXA-B may each refer to an area if (e.g., when) viewed toward a plane defined by the first direction axis DR1 and the second direction axis DR2 (e.g., the area in plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, the arrangement form of the light emitting regions PXA-R, PXA-G, and PXA-B may be a pentile (PENTILE®) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from one another. For example, in one or more embodiments, the area of the green light emitting region PXA-G may be smaller than that of the blue light emitting region PXA-B, but embodiments of the present disclosure are not limited thereto.

Hereinafter, FIG. 3 to FIG. 6 are each a cross-sectional view schematically showing a light emitting element according to one or more embodiments of the present disclosure. The light emitting element ED of one or more embodiments may include a first electrode EL1, a hole transport region HTR, an emission layer EML, an electron transport region ETR, and a second electrode EL2 stacked in order.

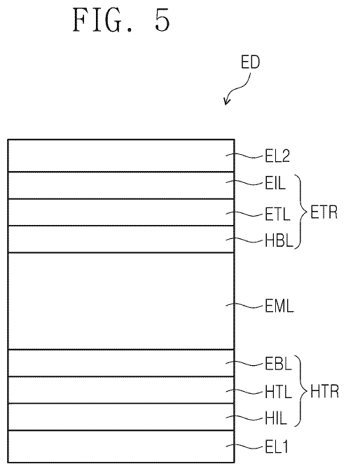

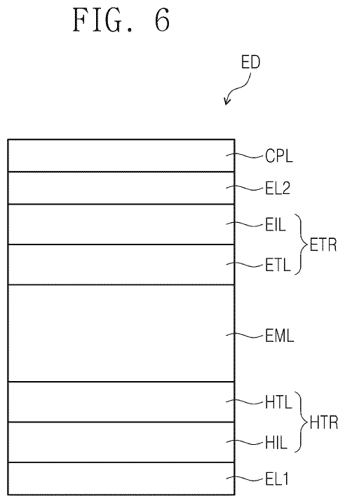

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Unlike the configuration illustrated in FIG. 5, in one or more embodiments, the hole injection layer HIL may not be provided in the hole transport region HTR. Compared with FIG. 4, FIG. 6 illustrates a cross-sectional view of a light emitting element ED of one or more embodiments including a capping layer CPL arranged on the second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in one or more embodiments, the first electrode EL1 may have a three-layer structure of ITO/Ag/ITO, but embodiments of the present disclosure are not limited thereto. The first electrode EL1 may include one of the above-described metal materials, a combination of at least two metal materials of the above-described metal materials, an oxide of the above-described metal materials, and/or the like. A thickness of the first electrode EL1 may be from about 700 angstroms (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of the hole injection layer HIL or the hole transport layer HTL, or may have a single layer structure formed of a hole injection material and/or a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

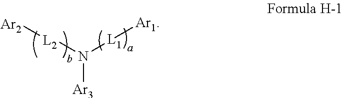

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and/or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented by Compound Group H:

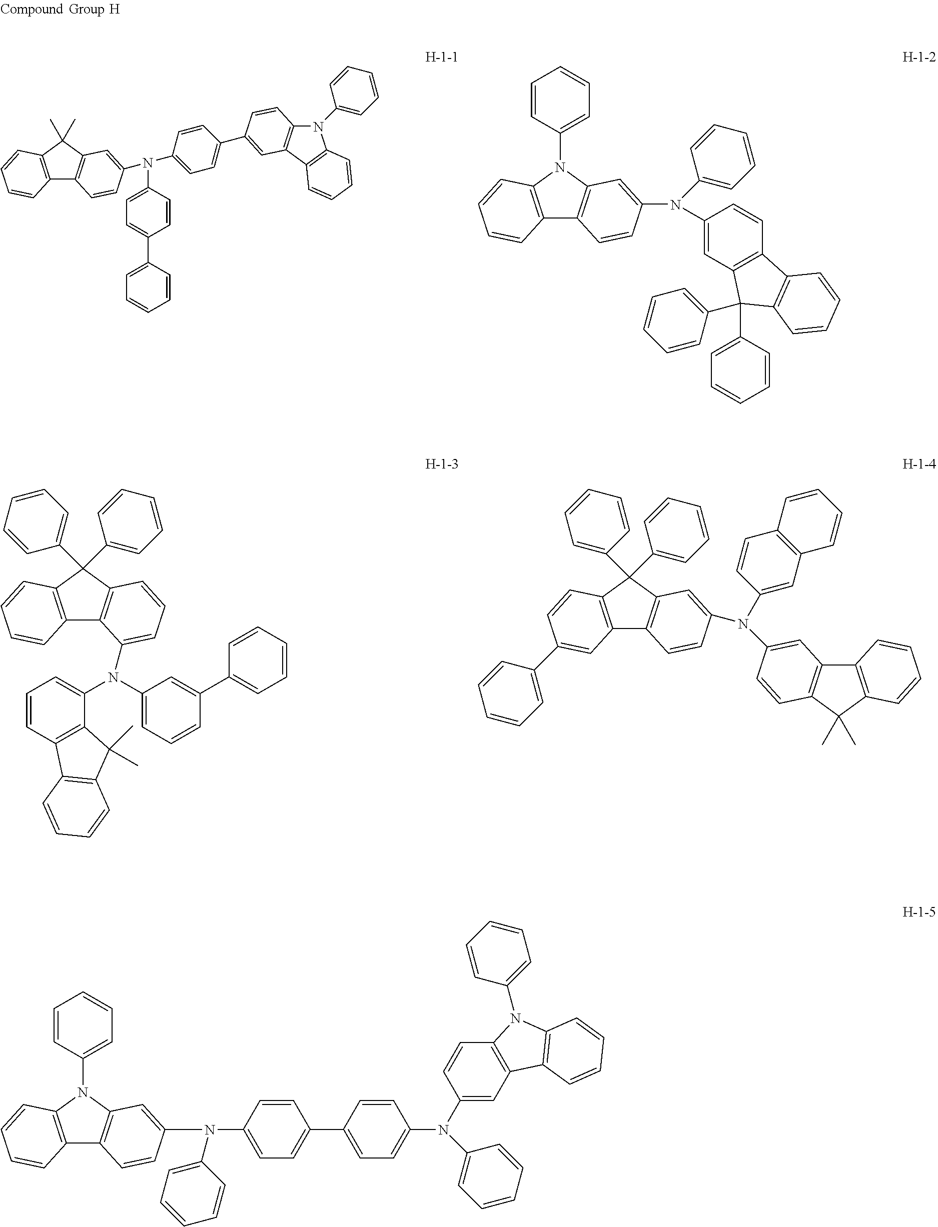

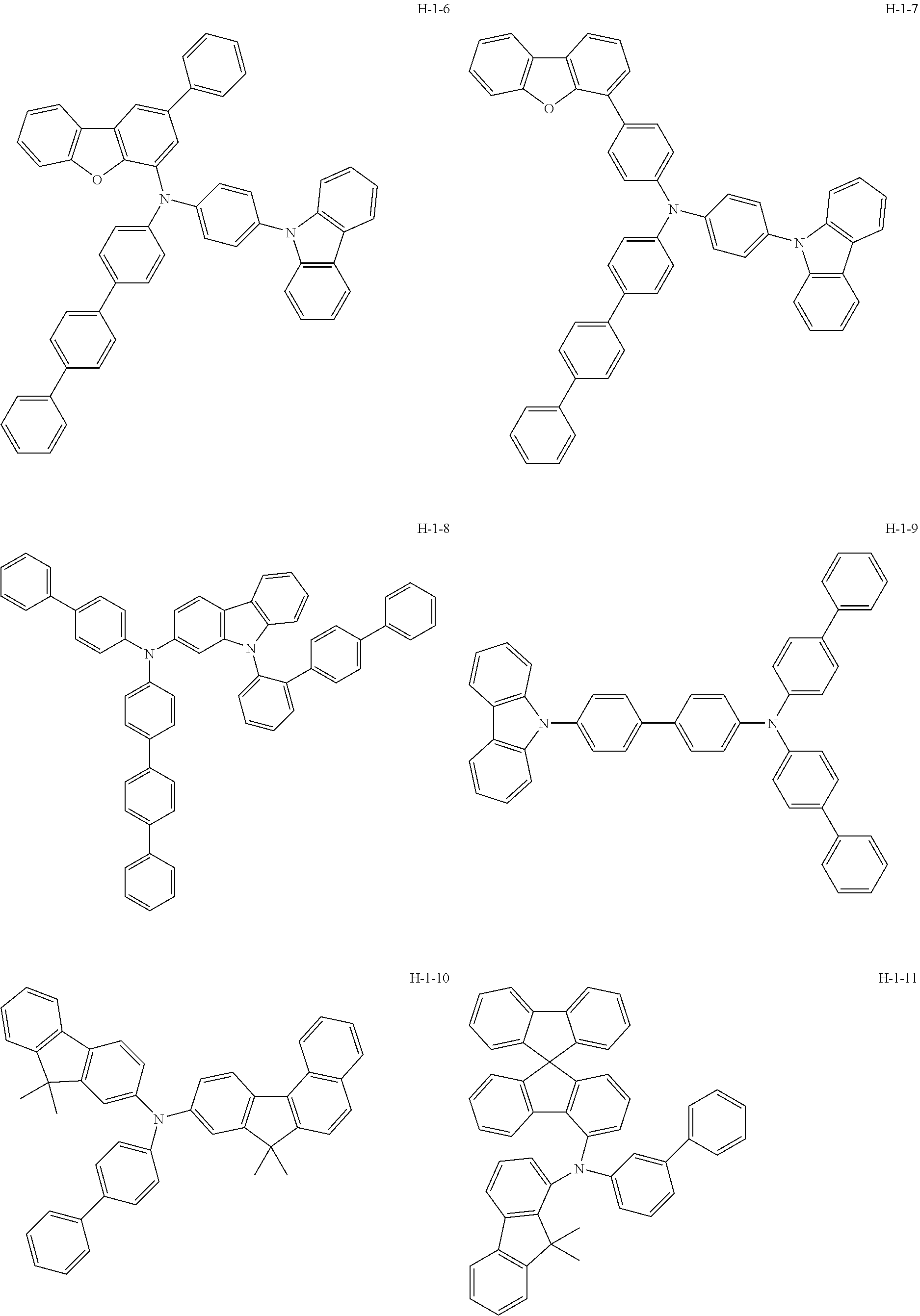

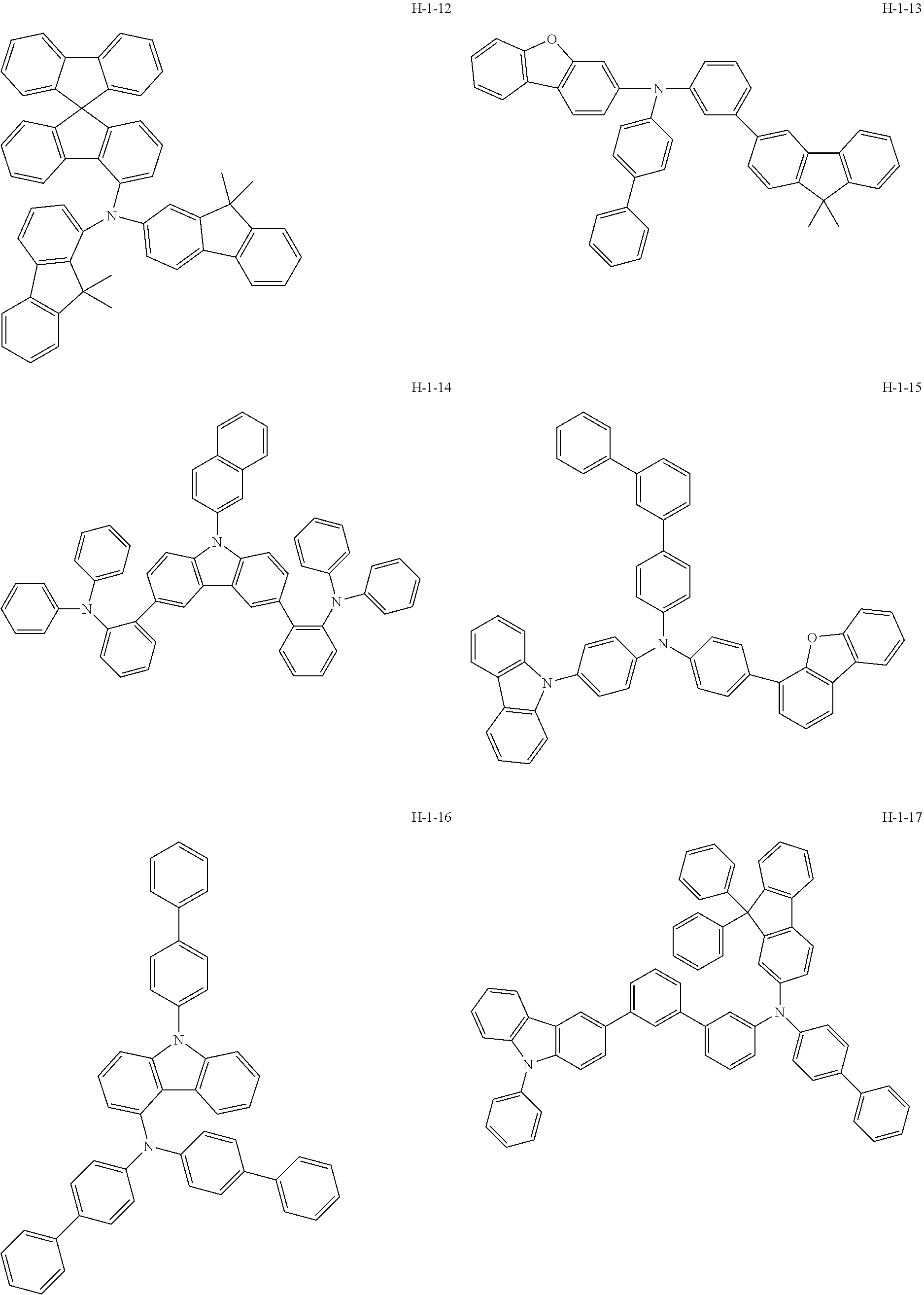

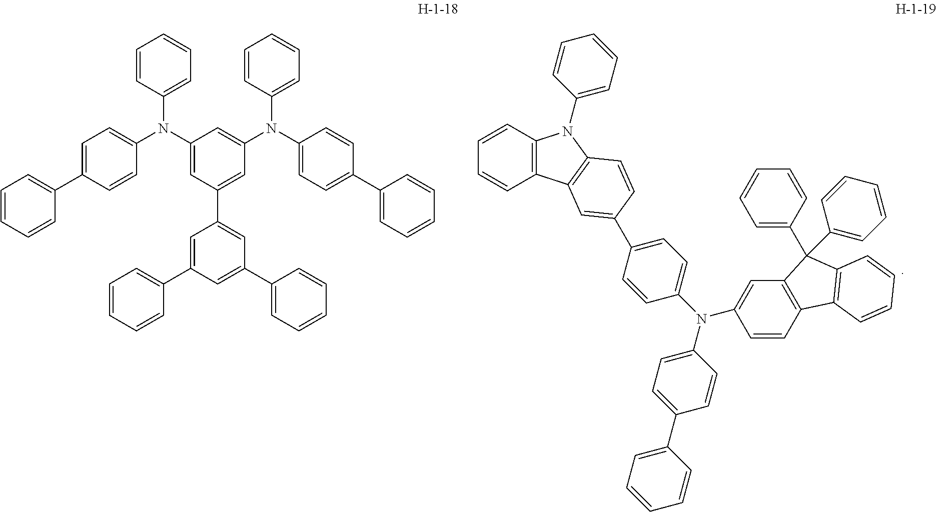

In one or more embodiments, the hole transport region HTR may include one or more selected from among a phthalocyanine compound such as copper phthalocyanine; N¹,N^{1′}-([1,1′-biphenyl]-4,4′-diyl)bis(N¹-phenyl-N⁴, N⁴-di-m-tolylbenzene-1,4-diamine) (DNTPD), 4,4′,4″-[tris(3-methyl phenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the hole transport region HTR may include one or more selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. If (e.g., when) the hole transport region HTR includes the hole injection layer HIL, the hole injection layer HIL may have, for example, a thickness of about 30 Å to about 1,000 Å. If (e.g., when) the hole transport region HTR includes the hole transport layer HTL, the hole transport layer HTL may have a thickness of about 30 Å to about 1,000 Å. For example, if (e.g., when) the hole transport region HTR includes the electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL, and the electron blocking layer EBL satisfy the above-described respective ranges, satisfactory hole transport properties may be achieved without a substantial increase in driving voltage.

In one or more embodiments, the hole transport region HTR may further include a charge generating material to increase conductivity (e.g., electric conductivity) in addition to one or more of the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal (e.g., metal halide) compound, a quinone derivative, a metal oxide, or a cyano group-containing compound, but embodiments of the present disclosure are not limited thereto. For example, in one or more embodiments, the p-dopant may include one or more selected from among a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce the electron injection from the electron transport region ETR to the hole transport region HTR.

In one or more embodiments, the emission layer EML may include a first compound according to one or more embodiments of the present disclosure. The emission layer EML according to one or more embodiments may further include at least one selected from among second to fourth compounds. The second compound may include a fused ring of three rings, which contains a nitrogen atom as a ring-forming atom. The third compound may include a 6-membered ring group containing at least one nitrogen atom as a ring-forming atom. The fourth compound may include an organometallic complex. The second to fourth compounds will be described in more detail later.

Herein, the first compound may be referred to as a fused polycyclic compound according to one or more embodiments of the present disclosure. In one or more embodiments, the fused polycyclic compound may include a fused ring of 13 rings as a central structure (i.e., core structure or skeleton structure), and the central structure may include at least one substituent instead of a hydrogen. The central structure may include three boron atoms and six heteroatoms as ring-forming atoms, and the six heteroatoms may each independently be N, O, or S. In one or more embodiments, in the fused polycyclic compound according to one or more embodiments, the central structure may be one in which the distributions of HOMO (highest occupied molecular orbital) and LUMO (lowest unoccupied molecular orbital) orbitals are separated. In one or more embodiments, the fused polycyclic compound according to one or more embodiments may be a charge-transfer type (kind) (CT) in which the distributions of HOMO and LUMO orbitals are separated. In addition, in the fused polycyclic compound according to one or more embodiments, the central structure may include a moiety having donor characteristics and a moiety having acceptor characteristics. Accordingly, the fused polycyclic compound according to one or more embodiments may exhibit a relatively very small AEST and may further accelerate reverse intersystem crossing (RISC). The fused polycyclic compound according to one or more embodiments may contribute to improving lifespan of a light emitting element ED. AEST indicates an absolute value of a difference in energy level between a triplet state and a singlet state of the fused polycyclic compound.

The light emitting element ED according to one or more embodiments may include the fused polycyclic compound according one or more embodiments. The fused polycyclic compound according to one or more embodiments may be represented by Formula 1.

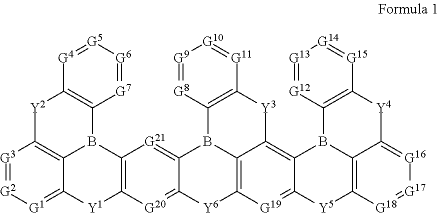

In Formula 1, Y¹ to Y⁶ may each independently be O, S, or NR^{y}. Y¹ to Y⁶ may correspond to the six heteroatoms described above. For example, in one or more embodiments, at least two selected from among Y¹ to Y⁶ may be O, and at least one selected from among the others may be NR^{y}.

At least one selected from among G¹ to G²¹ may be CR^{x1}, and the others may each independently be N or CR^{x2}. For example, in one or more embodiments, at least one selected from among G¹ to G²¹ may be CR^{x1}, and the others may each independently be N or CR^{x2}.

R^{x1} may be deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. R^{x1} is not hydrogen. R^{x1} may correspond to at least one of the substituents described above.

R^{x2} and R^{y} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. For example, in one or more embodiments, R^{x2} may be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. R^{y} may be a substituted or unsubstituted aryl group having 6 to 30 ring-forming carbon atoms.

In Formula 1, if (e.g., when) G² is CR^{x1} or CR^{x2}, R^{x1} and R^{x2} are not substituted or unsubstituted amine groups. If (e.g., when) G¹⁷ is CR^{x1} or CR^{x2}, R^{x1} and R^{x2} are not substituted or unsubstituted amine groups. If (e.g., when) G² is CR^{x1} or CR^{x2}, a carbon atom of G² is indirectly positioned para to an adjacent boron atom, and no substituted or unsubstituted amine group is bonded to the carbon atom of G². If (e.g., when) G¹⁷ is CR^{x1} or CR^{x2}, a carbon atom of G¹⁷ is indirectly positioned para to an adjacent boron atom, and no substituted or unsubstituted amine group is bonded to the carbon atom of G¹⁷.

The fused polycyclic compound according to one or more embodiments may include a chemical structure in which any hydrogen in its molecule is substituted with deuterium. For example, the fused polycyclic compound according to one or more embodiments may include deuterium as a substituent or may include a substituent substituted with deuterium. When the fused polycyclic compound according to one or more embodiments includes deuterium, the deuterium atom may be directly or indirectly bonded to the central structure. For example, in one or more embodiments, in Formula 1, a plurality of G¹ to G²¹ may each be CR^{x2}, and at least one selected from among a plurality of R^{x2} may be deuterium. In one or more embodiments, in Formula 1, a plurality of G¹ to G²¹ may each be CR^{x2}, and at least one selected from among a plurality of R^{x2} may include deuterium as a substituent. However, this is presented as an example, and embodiments of the present disclosure are not limited thereto.

In one or more embodiments, the fused polycyclic compound represented by Formula 1 may be represented by any one selected from among Formulas 1-A1 to 1-A8. Formulas 1-A1 and 1-A4 may specifically denote Y³, Y⁶, and G⁵ from Formula 1. Formulas 1-A2 and 1-A5 may specifically denote Y³, Y⁶, and G¹⁰ from Formula 1. Formulas 1-A3 and 1-A6 may specifically denote Y³, Y⁶, and G¹⁴ from Formula 1. Formula 1-A7 may specifically denote Y³, Y⁶, G⁹, and G¹⁰ from Formula 1. Formula 1-A8 may specifically denote Y³, Y⁶, G¹⁰, and G¹¹ from Formula 1.

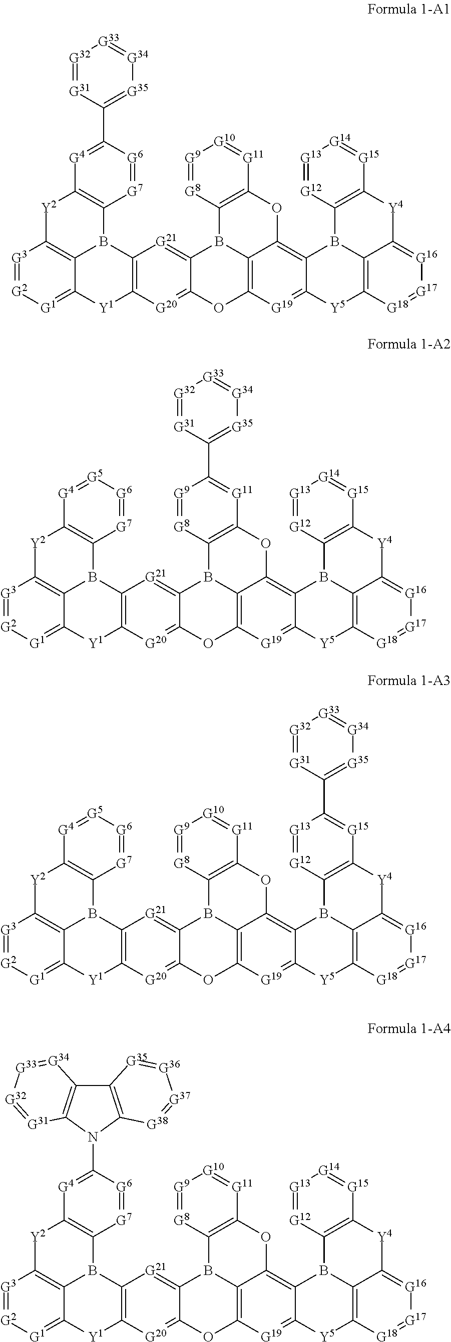

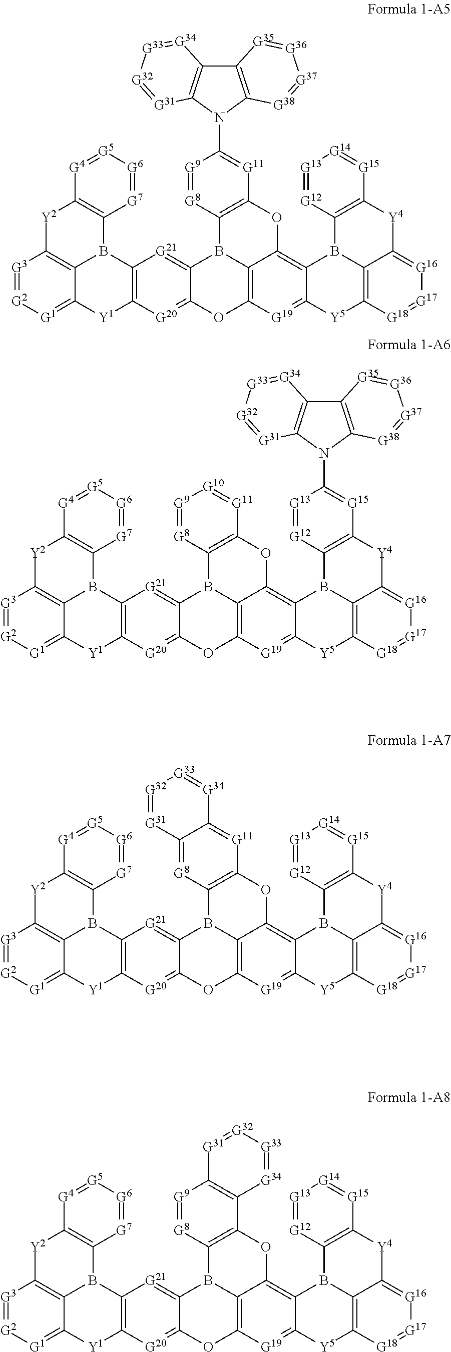

In Formulas 1-A1 to 1-A8, the same descriptions as in Formula 1 may be applied to Y¹, Y², Y⁴, Y⁵, and G¹ to G²¹. G³¹ to G³⁸ may each independently be N or CR^{X3}. For example, in one or more embodiments, G³¹ to G³⁸ may each independently be CR^{X3}.

R^{X3} may be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. For example, in one or more embodiments, R^{X3} may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms.

In one or more embodiments, the fused polycyclic compound represented by Formula 1 may be represented by any one selected from among Formulas 1-B1 to 1-B4. Formulas 1-B1 to 1-B4 may specifically denote any one selected from among G¹ to G²¹ from Formula 1.

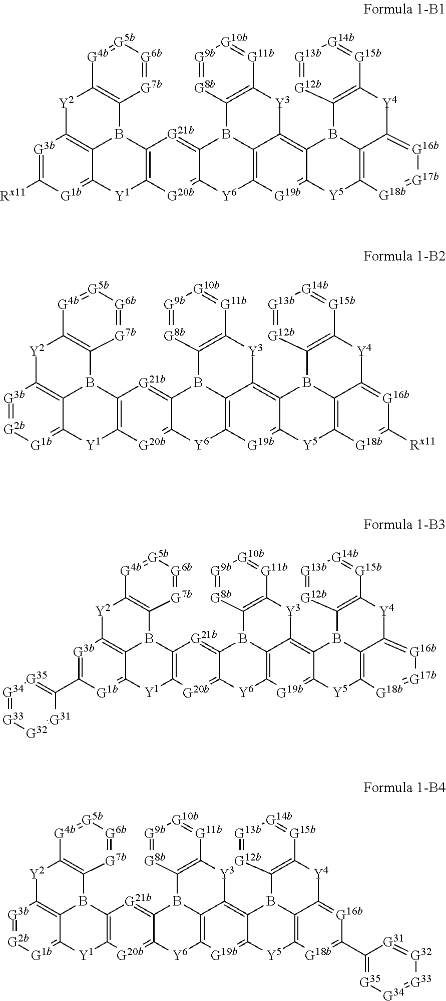

In Formulas 1-B1 to 1-B4, the same descriptions as in Formula 1 may be applied to Y¹ to Y⁶, and R^{x2}. G^{1b} to G^{21b} and G³¹ to G³⁵ may each independently be N or CR^{x2}. For example, in one or more embodiments, G^{1b} to G^{21b} and G³¹ to G³⁵ may each independently be CR^{x2}.

In Formulas 1-B1 to 1-B4, R^{x11} may be a substituted or unsubstituted alkyl group having 1 to 20 carbon atoms. For example, in one or more embodiments, R^{x11}may be a substituted or unsubstituted t-butyl group. However, this is presented as an example, and embodiments of the present disclosure are not limited thereto.

In one or more embodiments, the fused polycyclic compound represented by Formula 1 may be represented by Formula 2. Formula 2 may specifically denote G¹ to G²¹ from Formula 1.

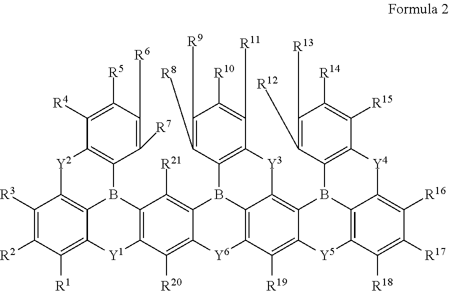

In Formula 2, the same descriptions as in Formula 1 may be applied to Y¹ to Y⁶. R¹ to R²¹ may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. For example, in one or more embodiments, at least one selected from among R¹ to R²¹ may each independently be deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms.

In Formula 2, at least one selected from among R¹ to R²¹ is not hydrogen. At least one selected from among R¹ to R²¹ may correspond to at least one of the substituents described above. In Formula 2, R² and R¹⁷ are not each a substituted or unsubstituted amine group.

In one or more embodiments, at least one selected from among R¹ to R²¹ may be a substituted or unsubstituted t-butyl group, a substituted or unsubstituted phenyl group, or a substituted or unsubstituted carbazole group. In one or more embodiments, at least one selected from among R¹ to R²¹ may be represented by any one selected from among R-1 to R-7. In one or more embodiments, in Formula 1, R^{x1} may be represented by any one selected from among R-1 to R-7. In R-3 and R-7, D is deuterium.

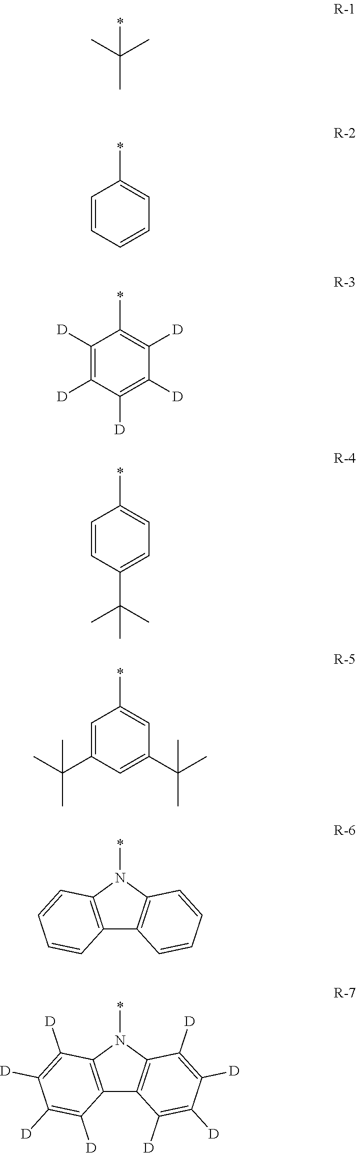

In one or more embodiments, the fused polycyclic compound represented by Formula 2 may be represented by any one selected from among Formulas 2-A1 to 2-A5 and Formulas 2-B1 to 2-B10. Formulas 2-A1 to 2-A5 may represent embodiments in which any one selected from among Y¹ to Y⁶ in Formula 2 is NR^{y} and the others are O. Formulas 2-B1 to 2-B10 may represent embodiments in which any two selected from among Y¹ to Y⁶ in Formula 2 may each independently be NR^{y} and the others are O.

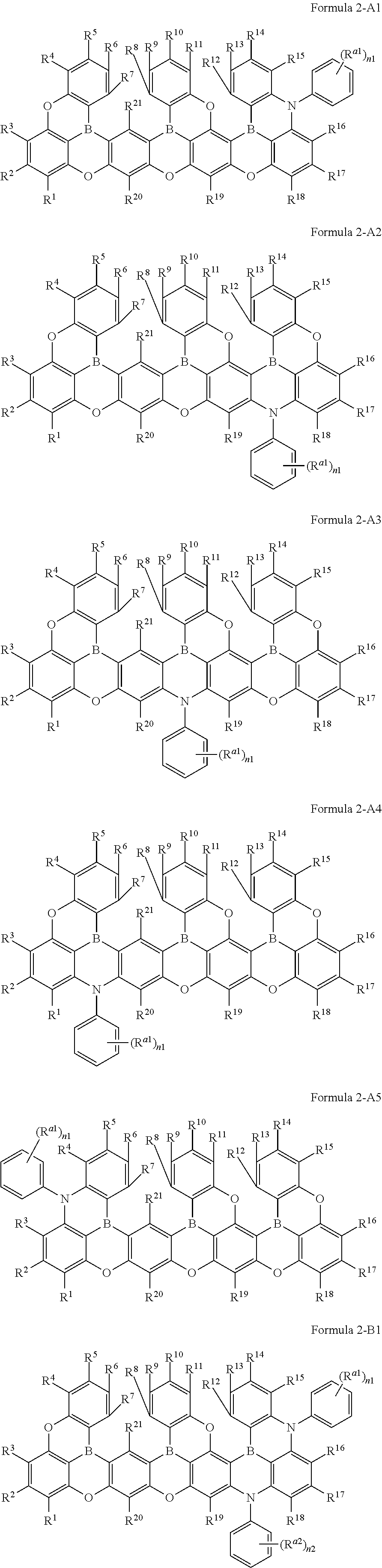

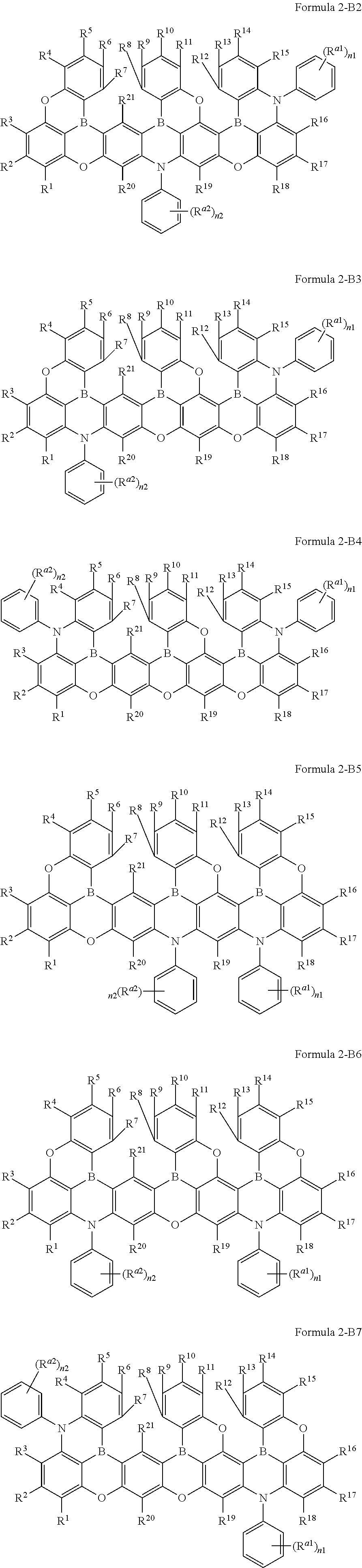

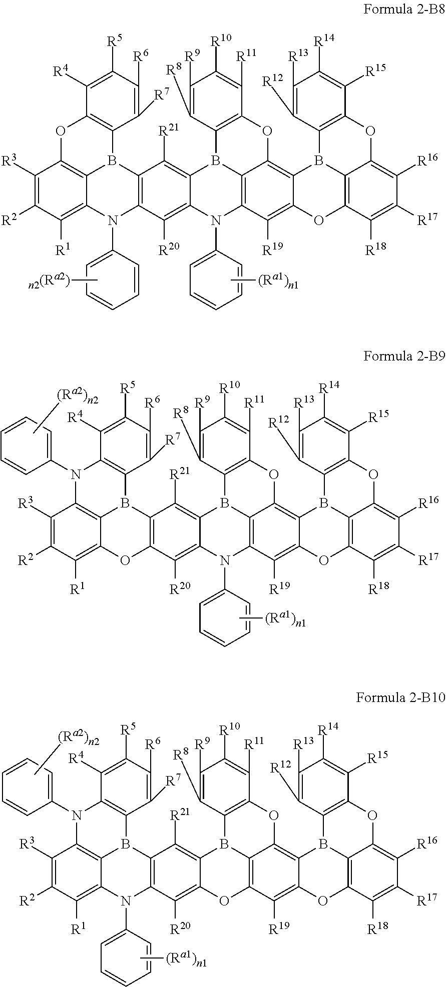

In Formulas 2-A1 to 2-A5 and Formulas 2-B1 to 2-B10, the same descriptions as in Formula 2 may be applied to R¹ to R²¹. R^{a1} and R^{a2} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring. For example, in one or more embodiments, R^{a1} and R^{a2} may each independently be hydrogen, deuterium, a substituted or unsubstituted alkyl group having 1 to 20 carbon atoms, or a substituted or unsubstituted aryl group having 6 to 30 ring-forming carbon atoms.

In Formulas 2-A1 to 2-A5 and Formulas 2-B1 to 2-B10, n1 and n2 may each independently be an integer of 0 to 5, and n1 represents the number of R^{a1}'s and n2 represents the number of R^{a2}'s. If (e.g., when) n1 is an integer of 2 or greater, a plurality of R^{a1}'s may all be the same, or at least one may be different from the others. The embodiment in which n1 is 0 may be the same as an embodiment in which n1 is 5 and five R^{a1}'s are each hydrogen. If (e.g., when) n2 is an integer of 2 or greater, a plurality of R^{a2′}ₛ may all be the same, or at least one may be different from the others. The embodiment in which n2 is 0 may be the same as an embodiment in which n2 is 5 and five R^{a2}'s are each hydrogen.

In one or more embodiments, in Formulas 2-A1 to 2-A5 and Formulas 2-B1 to 2-B10, a first ring group including R^{a1} and a second ring group including R^{a2} may each independently be a substituted or unsubstituted phenyl group, a substituted or unsubstituted biphenyl group, or a substituted or unsubstituted terphenyl group. In one or more embodiments, the first ring group including R^{a1} and the second ring group including R^{a2} may each independently be represented by any one selected from among RA-1 to RA-5. In one or more embodiments, in Formula 1, R^{y} may be a substituted or unsubstituted phenyl group, a substituted or unsubstituted biphenyl group, or a substituted or unsubstituted terphenyl group. In one or more embodiments, in Formula 1, R^{y} may be represented by any one selected from among RA-1 to RA-5.

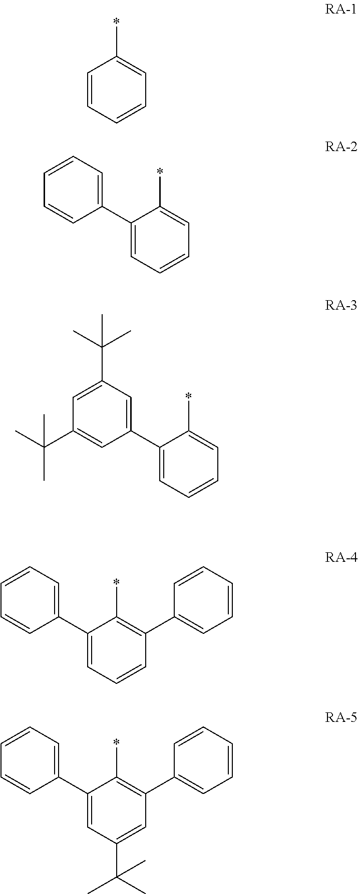 [SMILES: *c1ccccc1 ; *c1ccccc1-c1ccccc1 ; *c1ccccc1-c1cc(C(C)(C)C)cc(C(C)(C)C)c1 ; *c1c(-c2ccccc2)cccc1-c1ccccc1 ; *c1c(-c2ccccc2)cc(C(C)(C)C)cc1-c1ccccc1]

In one or more embodiments, the fused polycyclic compound represented by Formula 2 may be represented by any one selected from among Formulas 2-C1 to 2-C10 and Formulas 2-D1 to 2-D5. Formulas 2-C1 to 2-C10 may represent embodiments in which any three selected from among Y¹ to Y⁶ in Formula 2 may each independently be NR^{y} and the others are O. Formulas 2-D1 to 2-D5 may represent embodiments in which any four selected from among Y¹ to Y⁶ in Formula 2 may each independently be NR^{y} and the others are O.

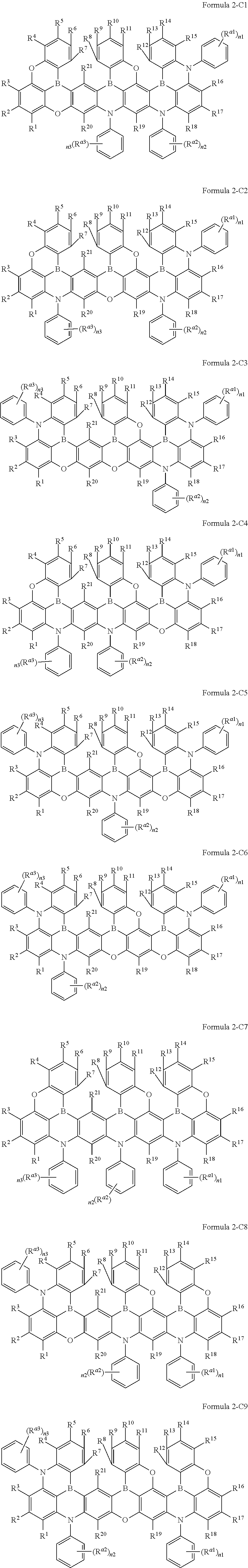

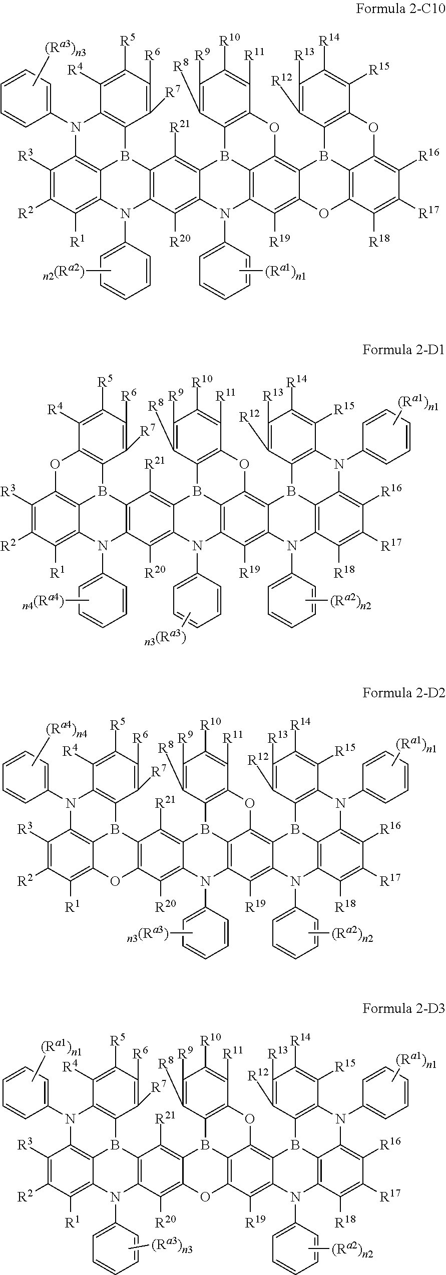

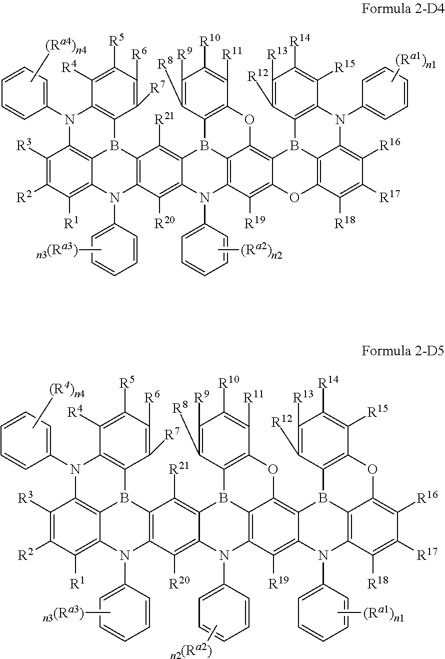

In Formulas 2-C1 to 2-C10 and Formulas 2-D1 to 2-D5, the same descriptions as in Formula 2 may be applied to R¹ to R²¹. R^{a1} to R^{a4} may each independently be hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring.

In Formulas 2-C1 to 2-C10 and Formulas 2-D1 to 2-D5, n1 to n4 may each independently be an integer of 0 to 5, and n1 represents the number of R^{a1}'s, n2 represents the number of R^{a2}'s, n3 represents the number of R^{a3}'s, and n4 represents the number of R^{a4}'s. The same descriptions as in Formulas 2-A1 to 2-A5 and Formulas 2-B1 to 2-B10 may be applied to n1, n2, R^{a1}, and R^{a2}.

If (e.g., when) n3 is an integer of 2 or greater, a plurality of R^{a3}'s may all be the same, or at least one may be different from the others. The embodiments in which n3 is 0 may be the same as embodiments in which n3 is 5 and five R^{a3}′ₛ are each hydrogen. If (e.g., when) n4 is an integer of 2 or greater, a plurality of R^{a4}'s may all be the same, or at least one may be different from the others. The embodiment in which n4 is 0 may be the same as embodiments in which n4 is 5 and five R^{a4′}ₛ are each hydrogen.

In one or more embodiments, the fused polycyclic compound represented by Formula 1 may be any one selected from compounds from Compound Group 1. The fused polycyclic compound according to one or more embodiments may be any one selected from among compounds from Compound Group 1. The light emitting element ED according to one or more embodiments may include at least one selected from among compounds from Compound Group 1. The emission layer EML may include at least any one selected from among compounds from Compound Group 1. In Compound Group 1, D is deuterium.

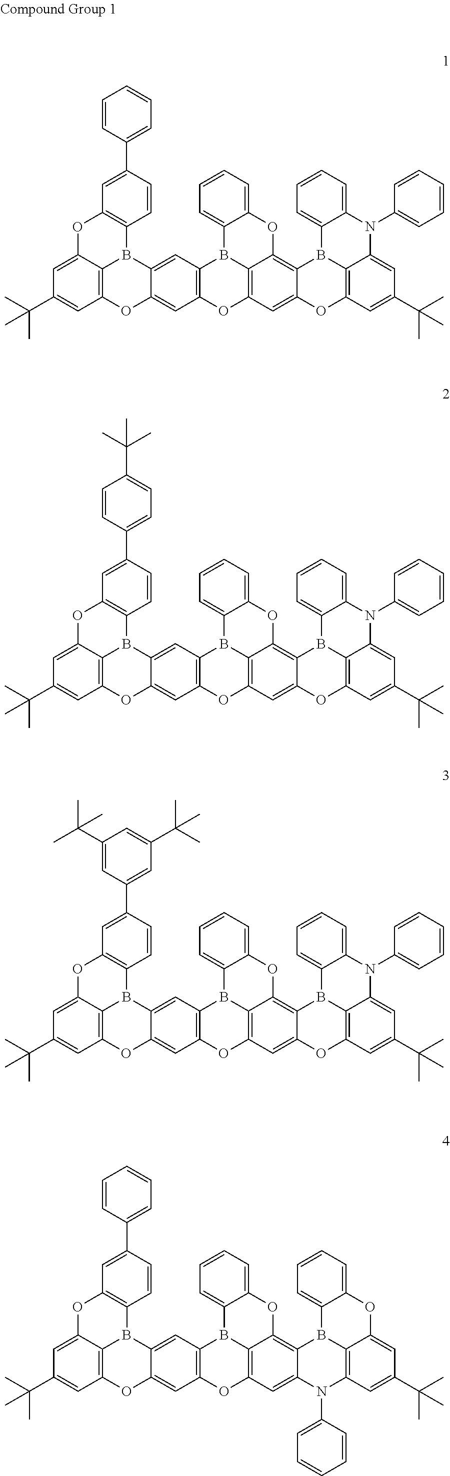

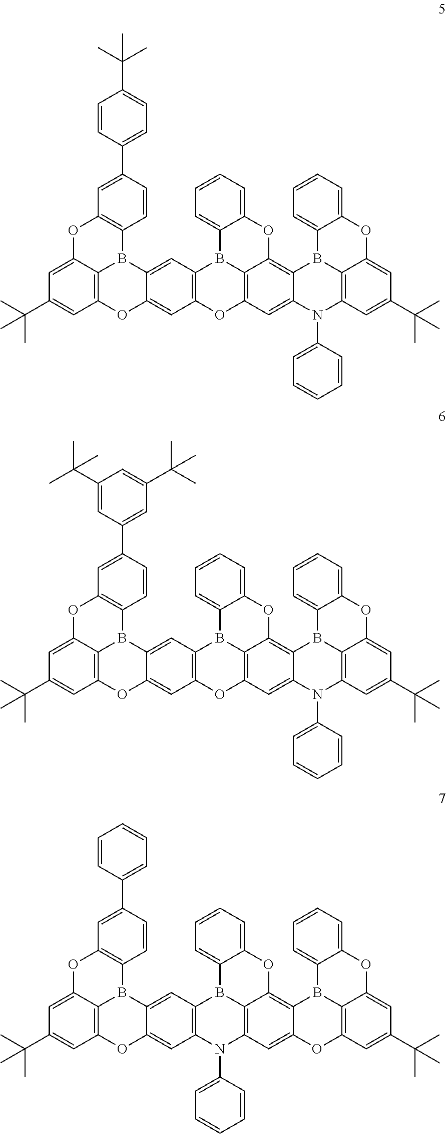

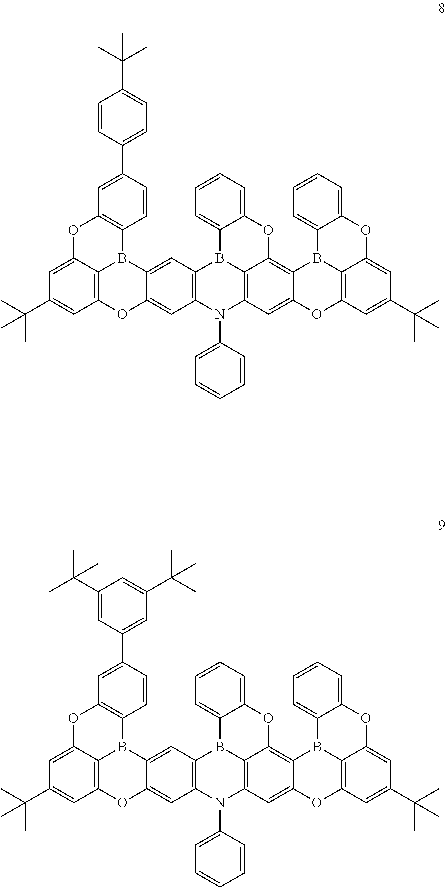

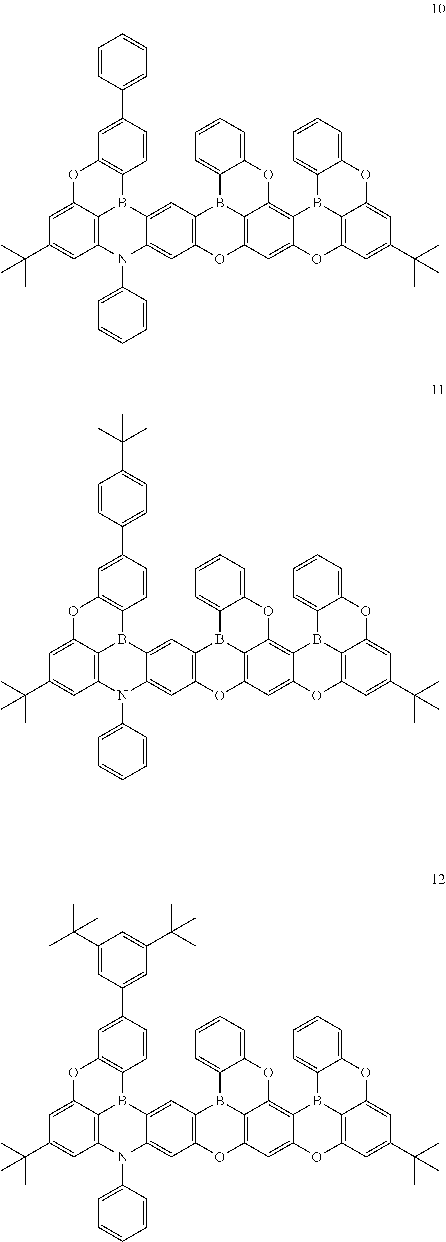

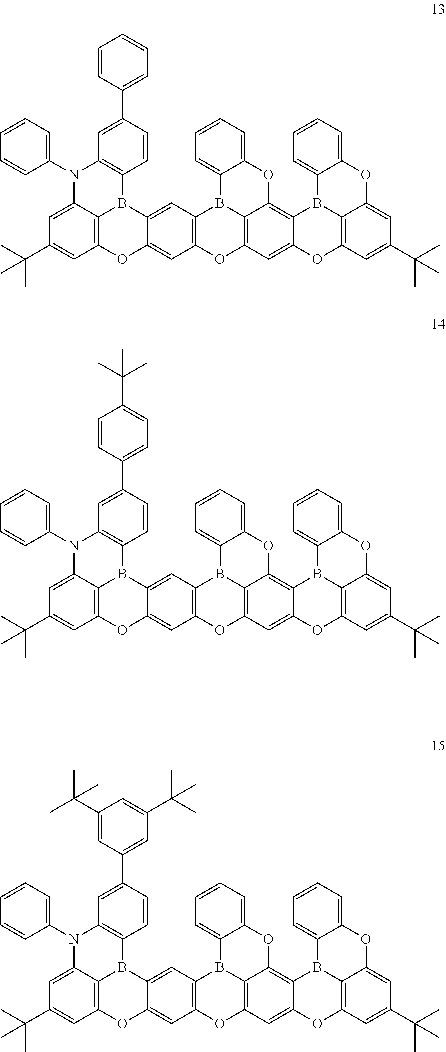

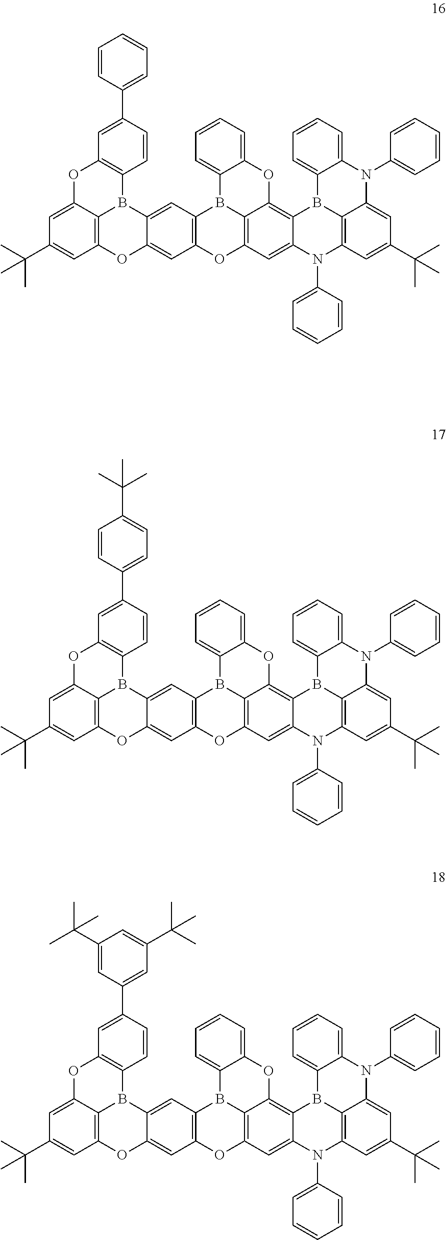 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1]

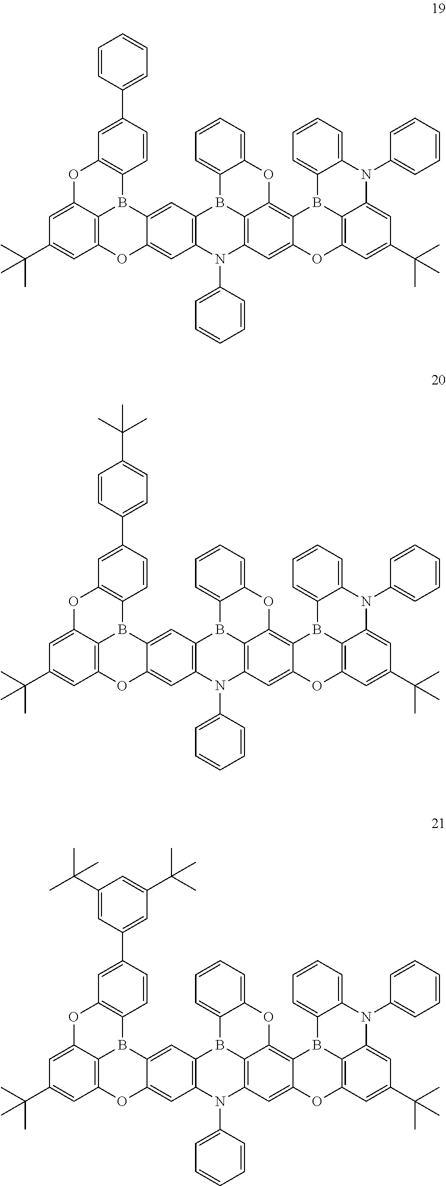 [SMILES: CC(C)(C)c1cc2c3c(c1)Oc1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1]

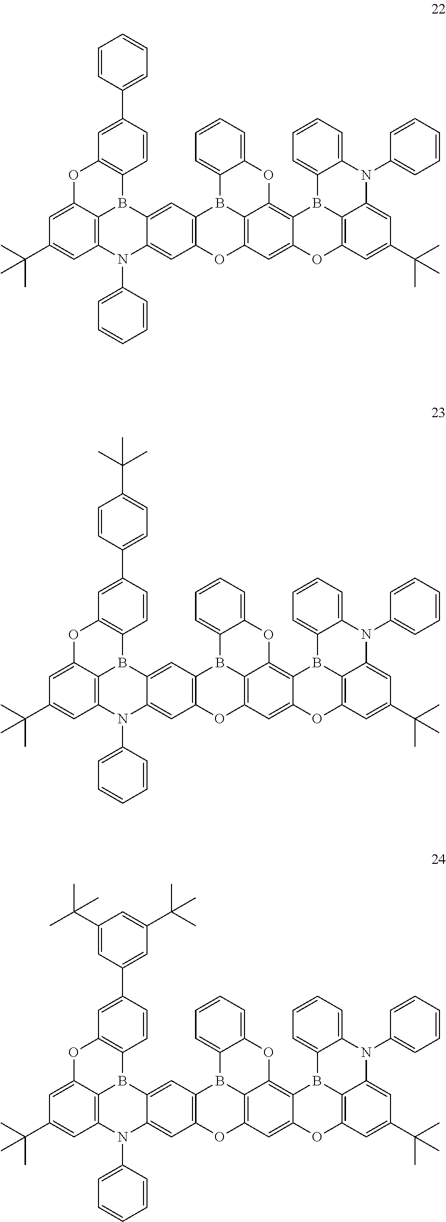 [SMILES: CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)O1)O4 ; CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1]

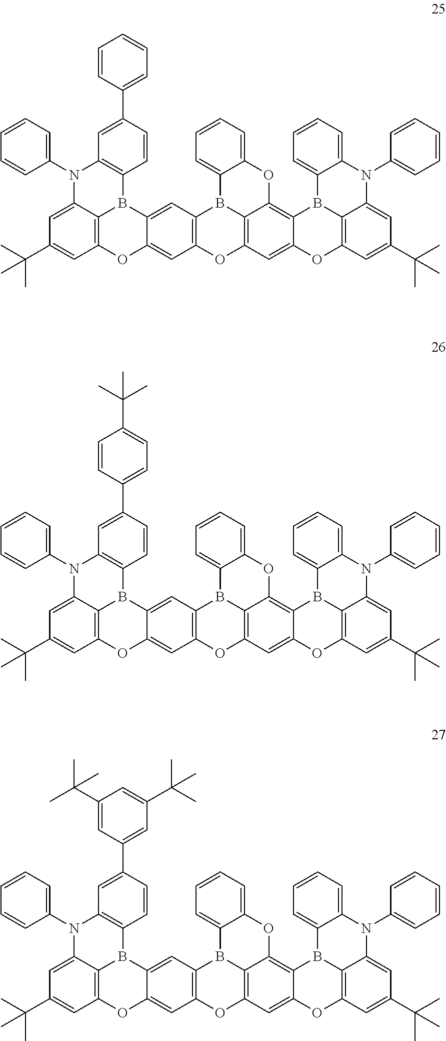 [SMILES: CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc(C(C)(C)C)c1]

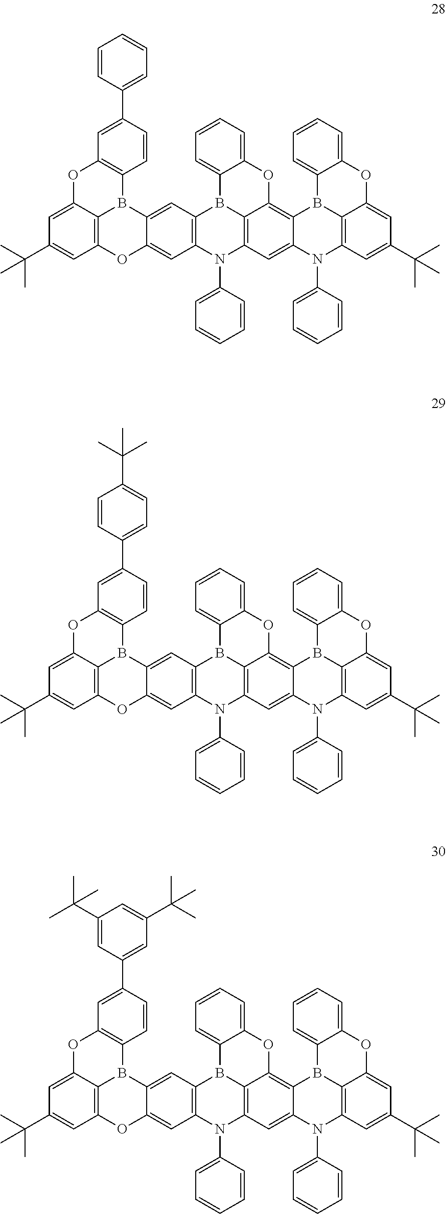

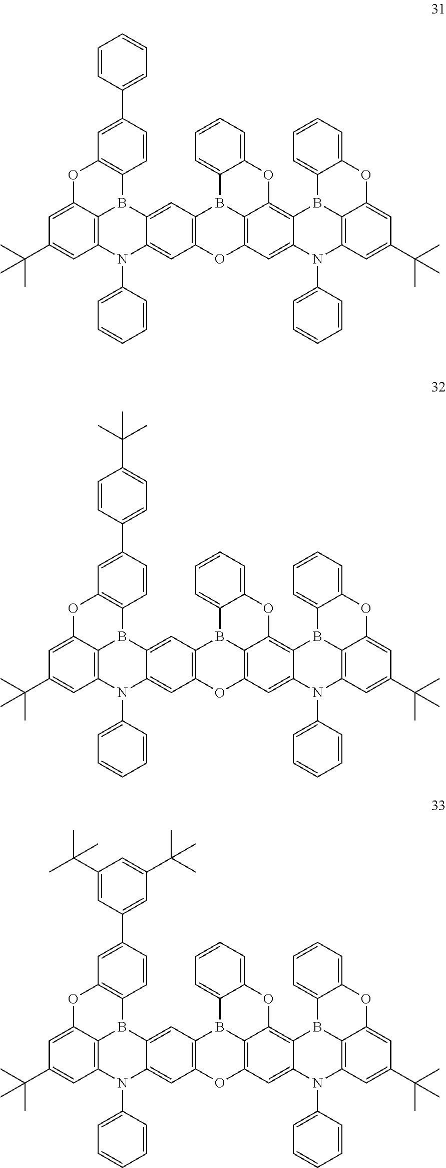

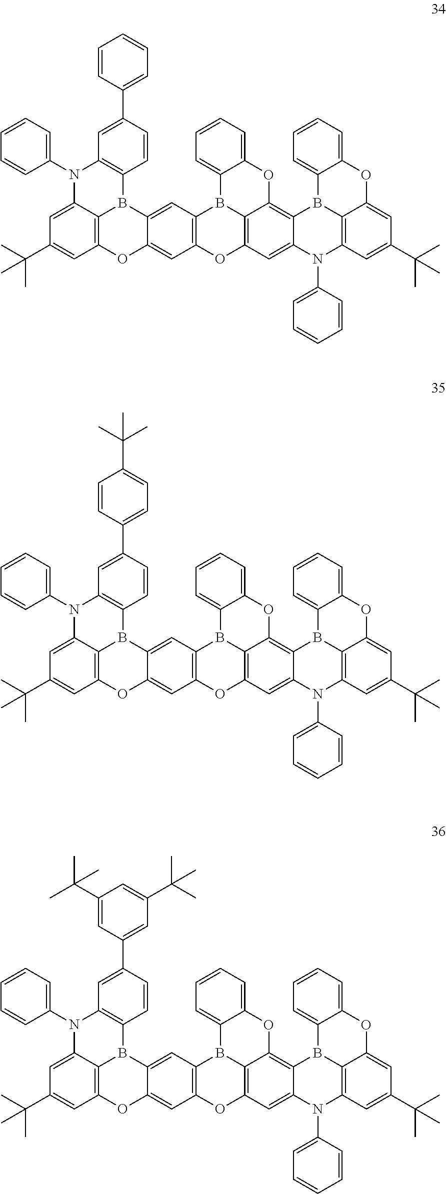

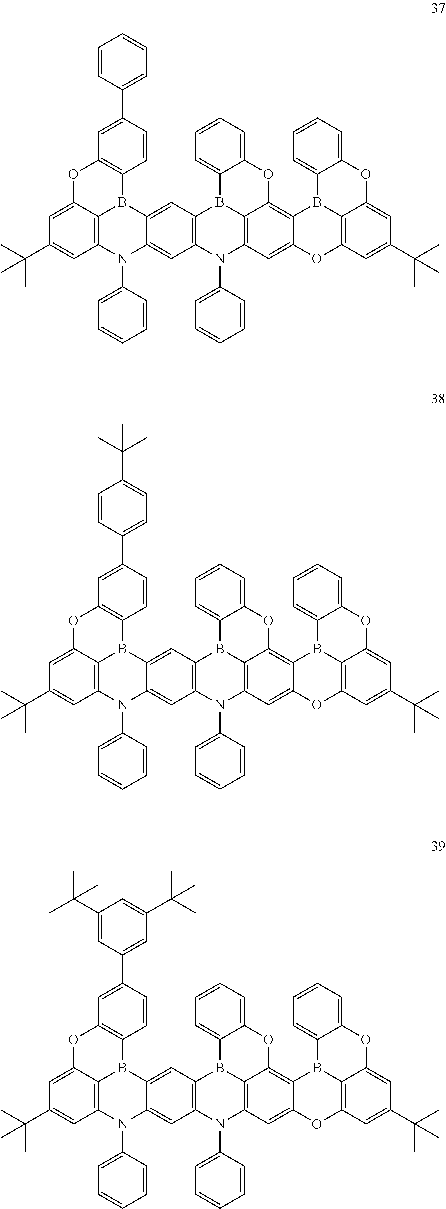

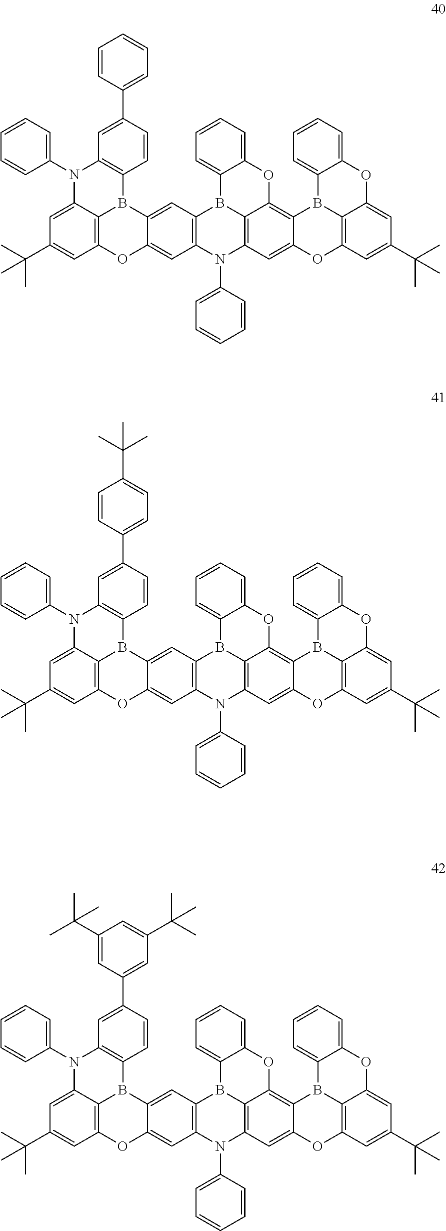

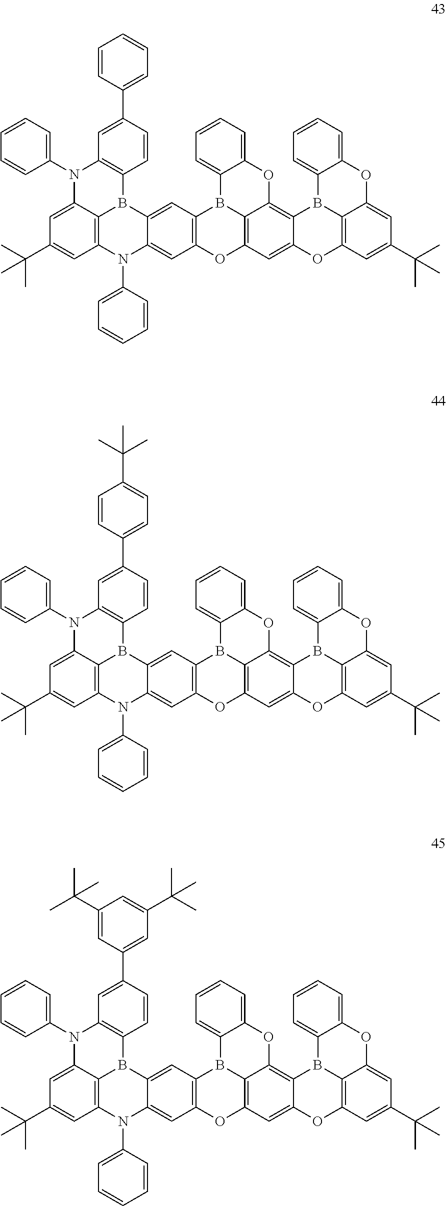

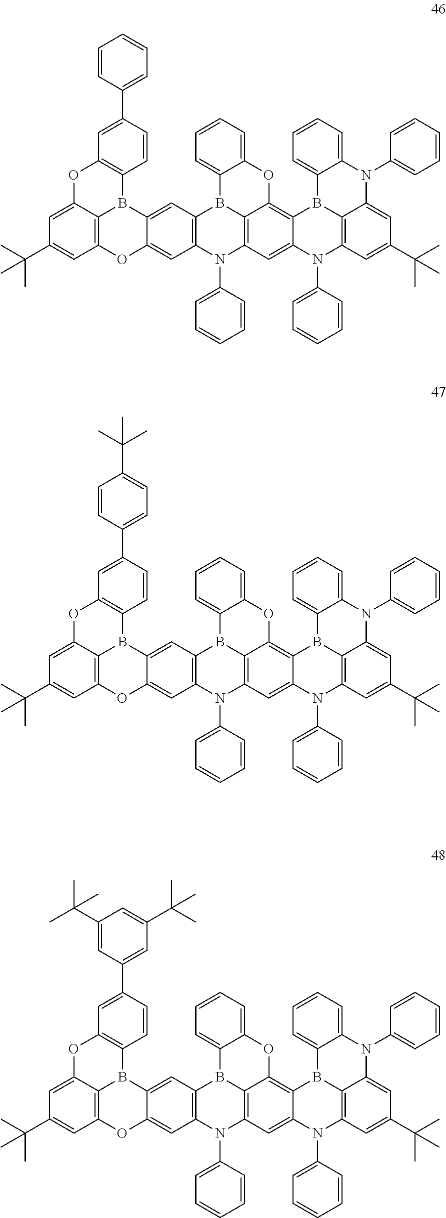 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1]

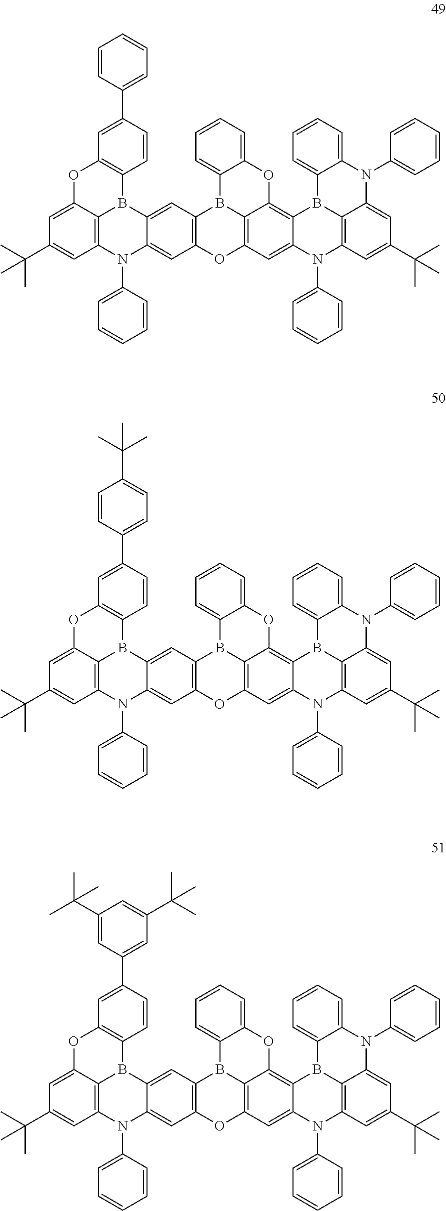 [SMILES: CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc(C(C)(C)C)c1]

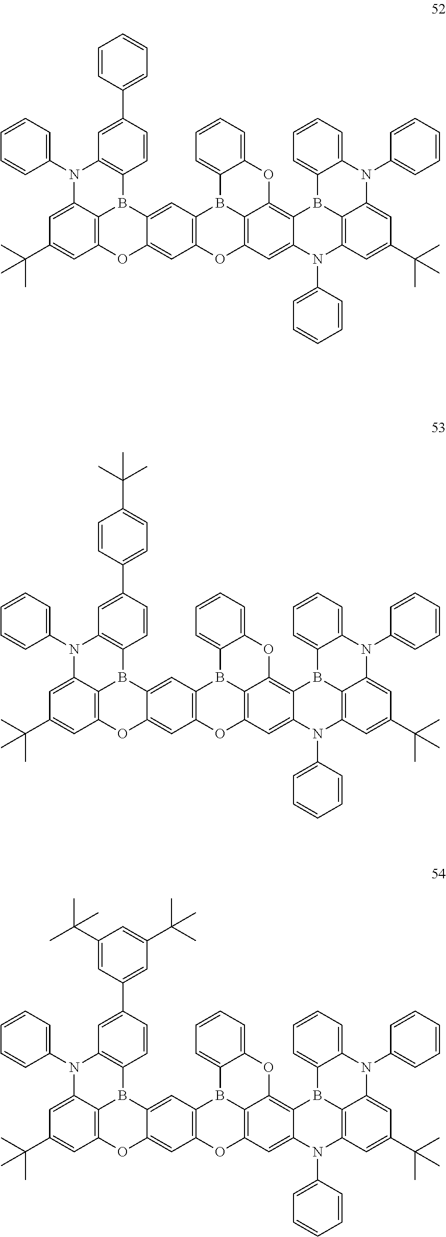 [SMILES: CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)N2c1ccccc1 ; CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1]

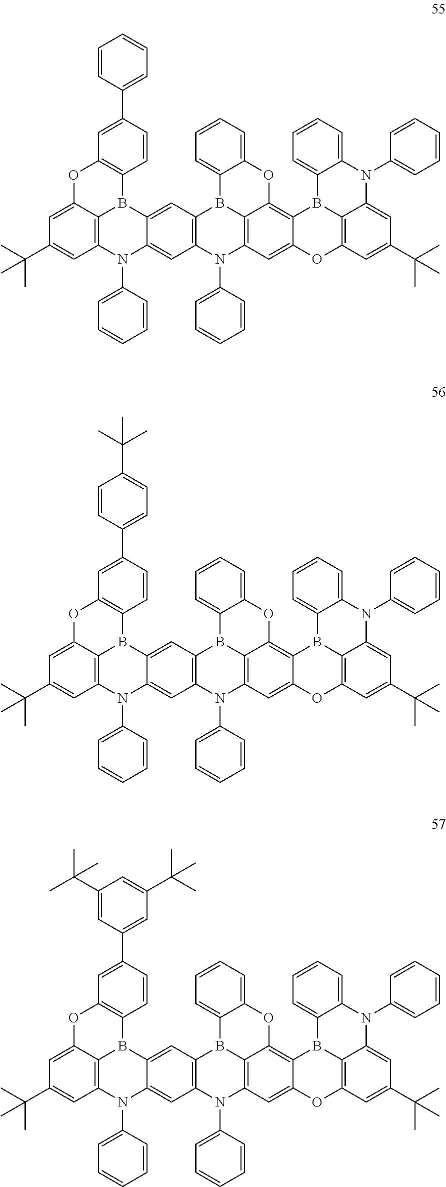 [SMILES: CC(C)(C)c1cc2c3c(c1)N(c1ccccc1)c1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1]

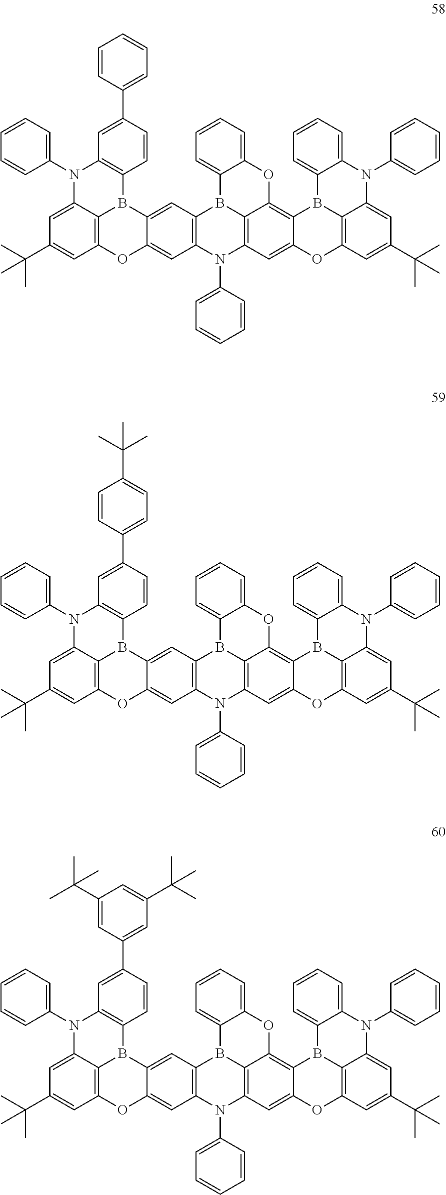 [SMILES: CC(C)(C)c1cc2c3c(c1)N(c1ccccc1)c1cc(-c4ccccc4)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1]

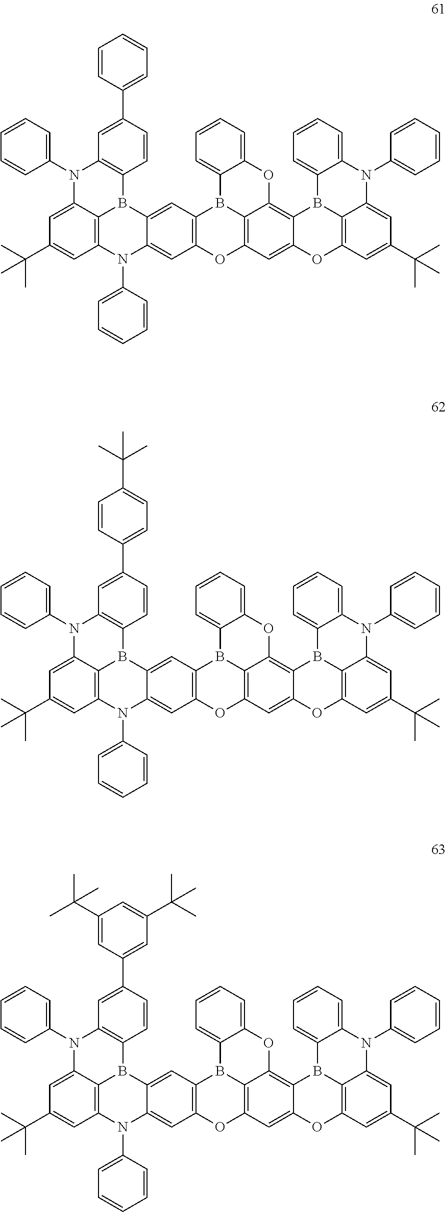 [SMILES: CC(C)(C)c1cc2c3c(c1)N(c1ccccc1)c1ccccc1B3c1c(cc3c4c1Oc1ccccc1B4c1cc4c(cc1O3)N(c1ccccc1)c1cc(C(C)(C)C)cc3c1B4c1ccc(-c4ccccc4)cc1N3c1ccccc1)O2 ; CC(C)(C)c1ccc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1]

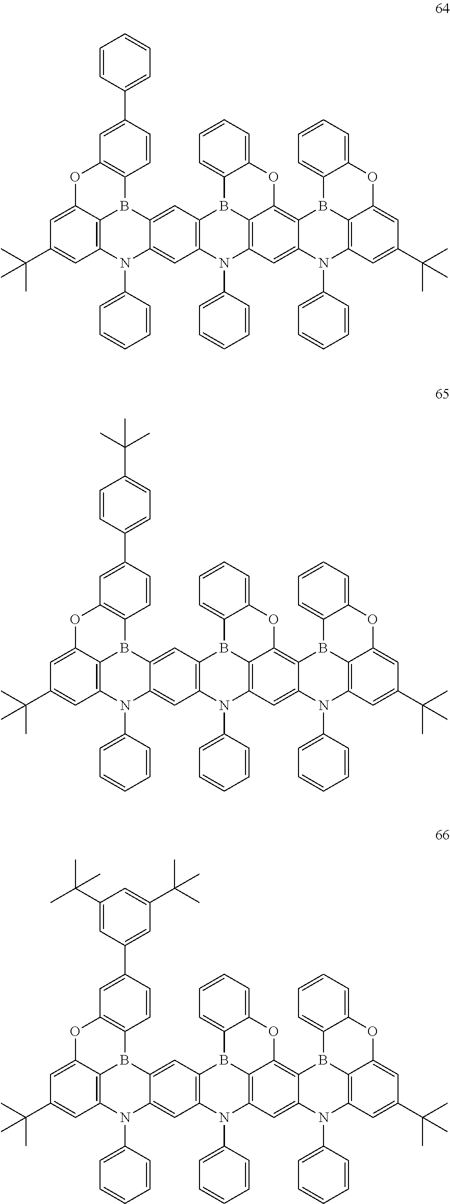

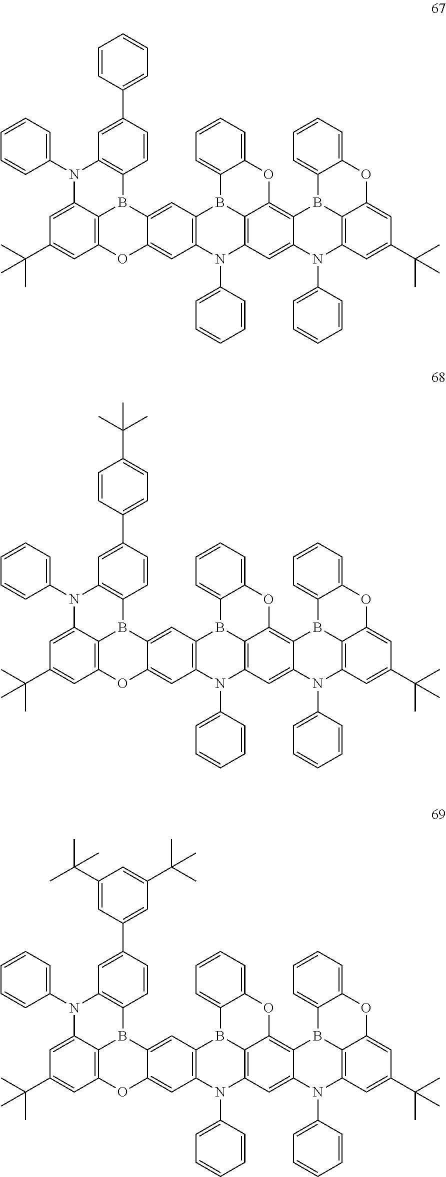

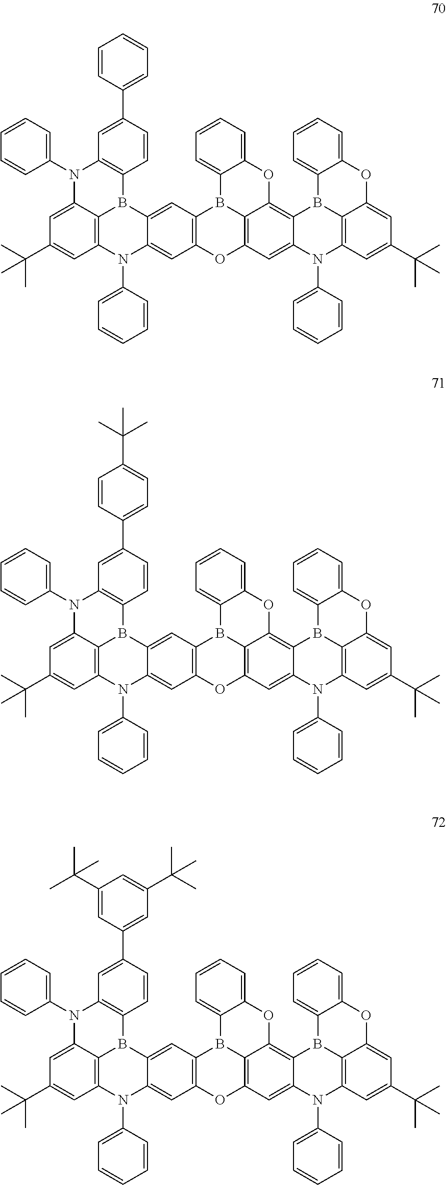

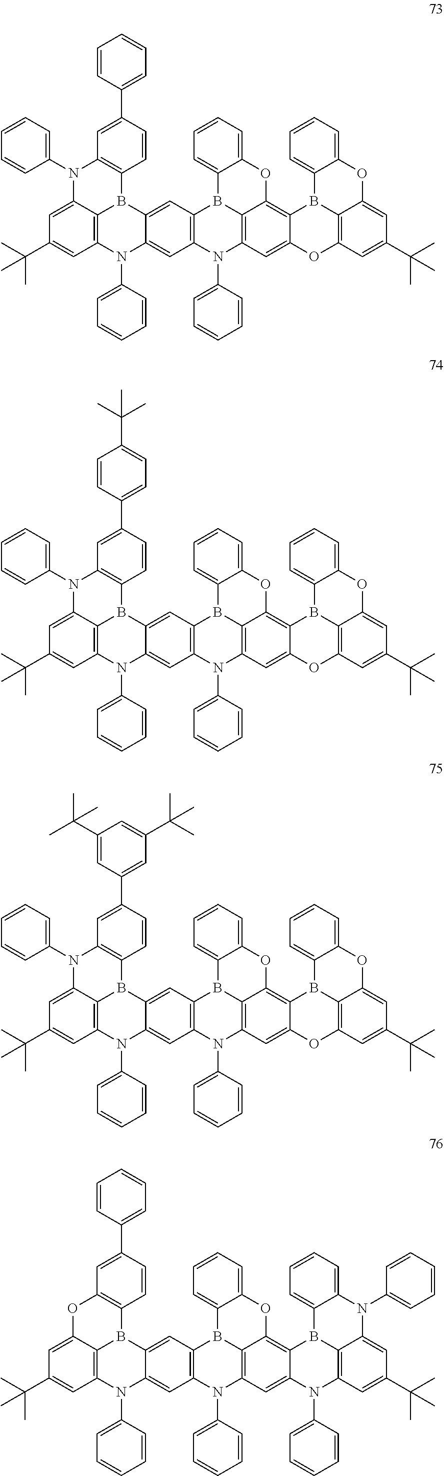

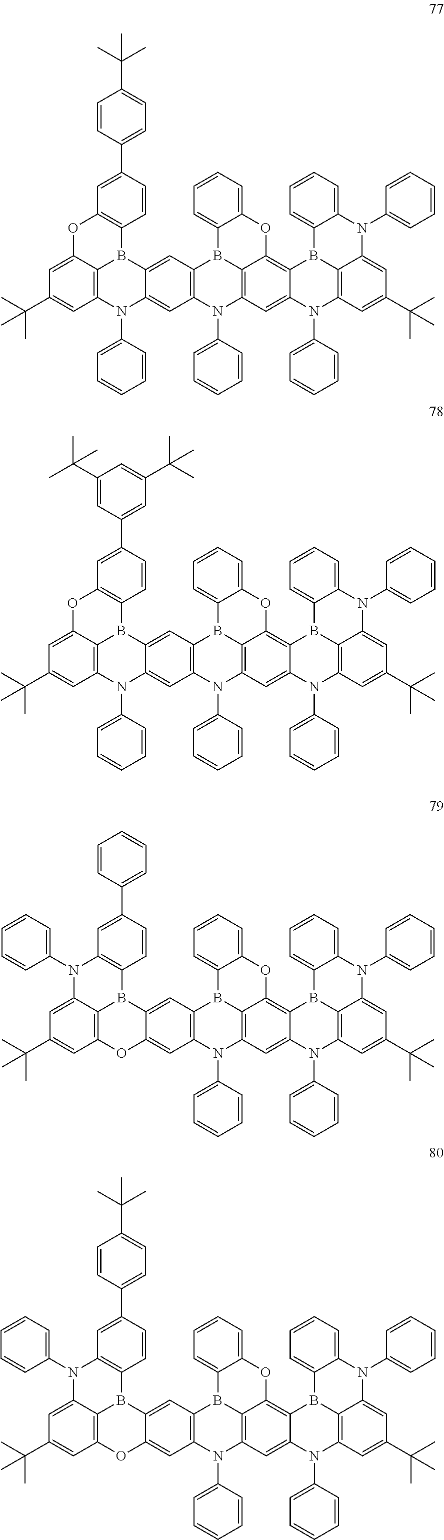

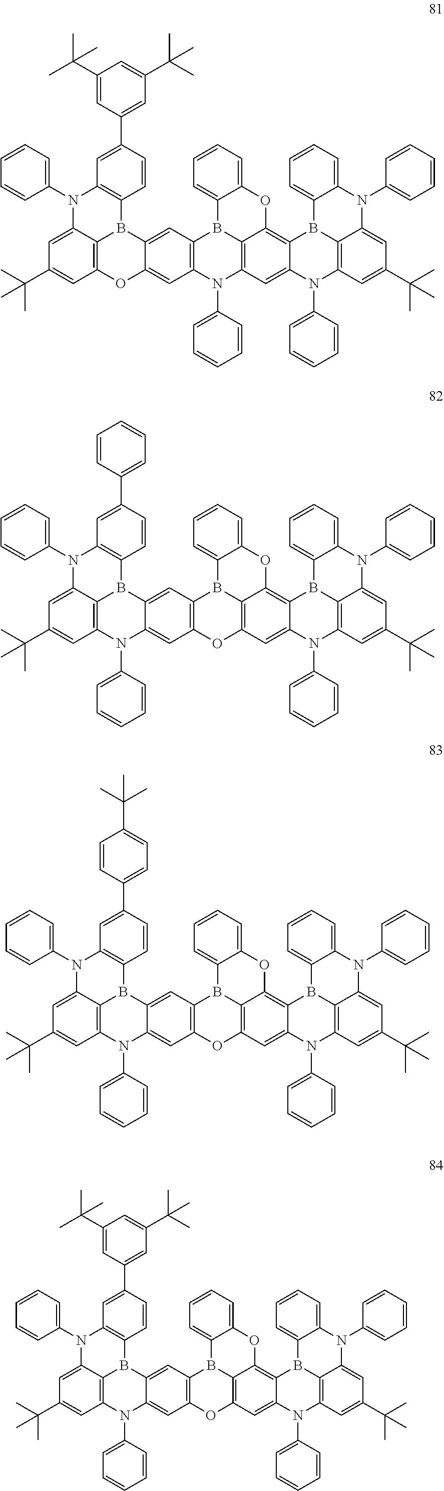

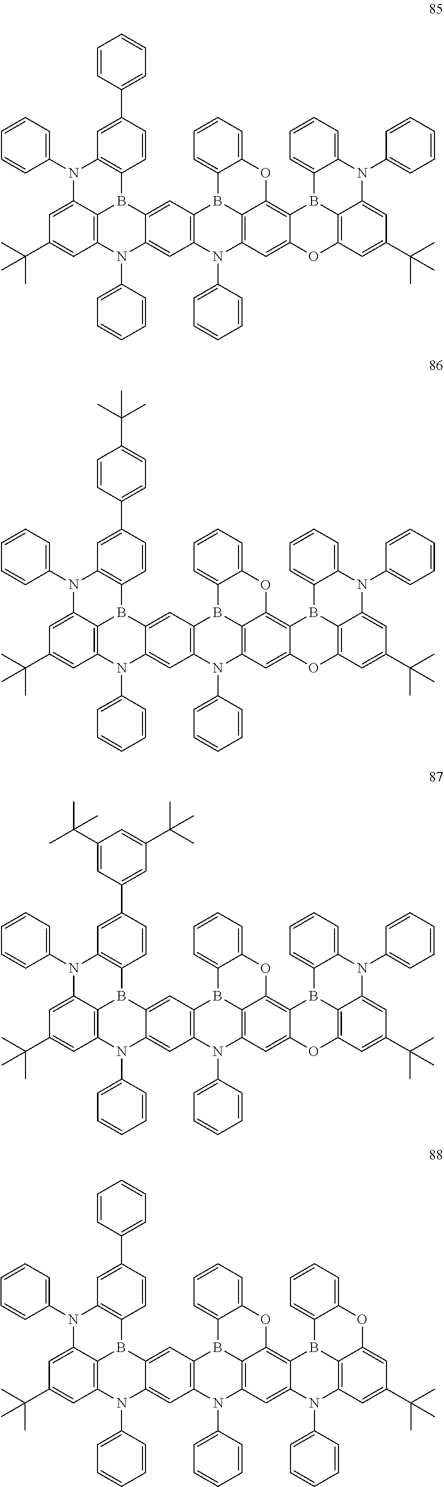

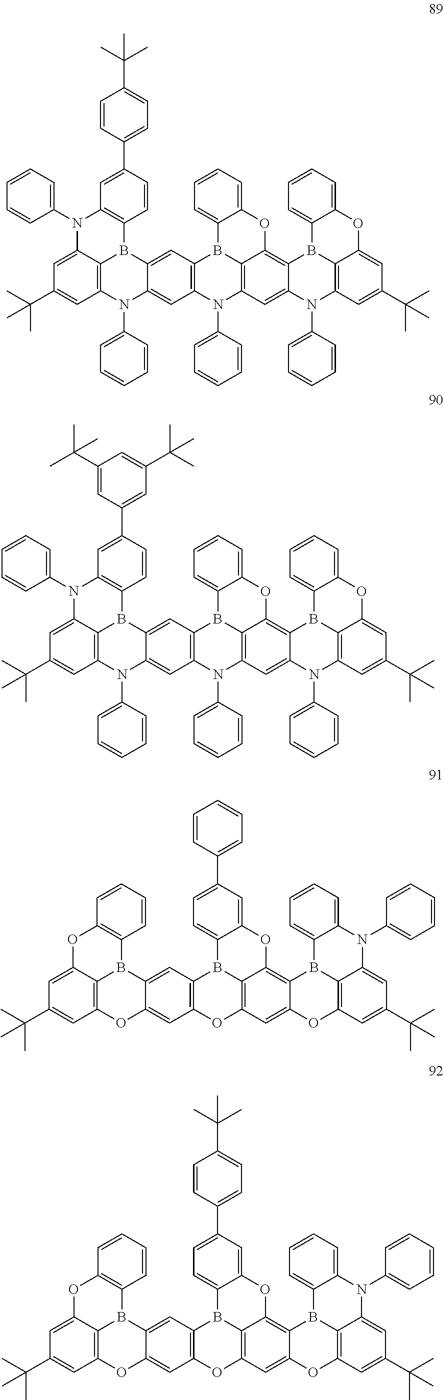

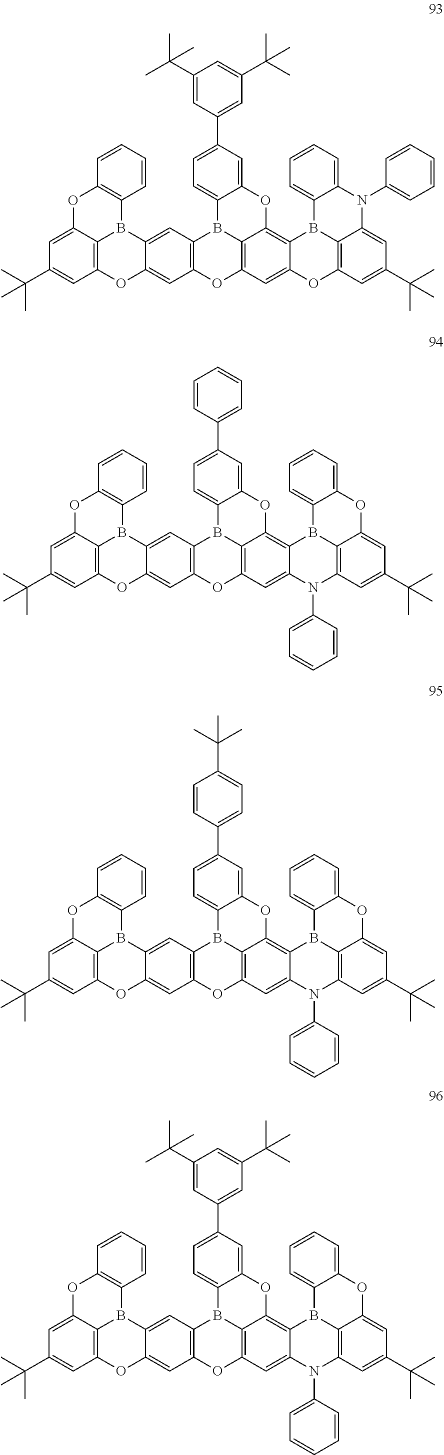

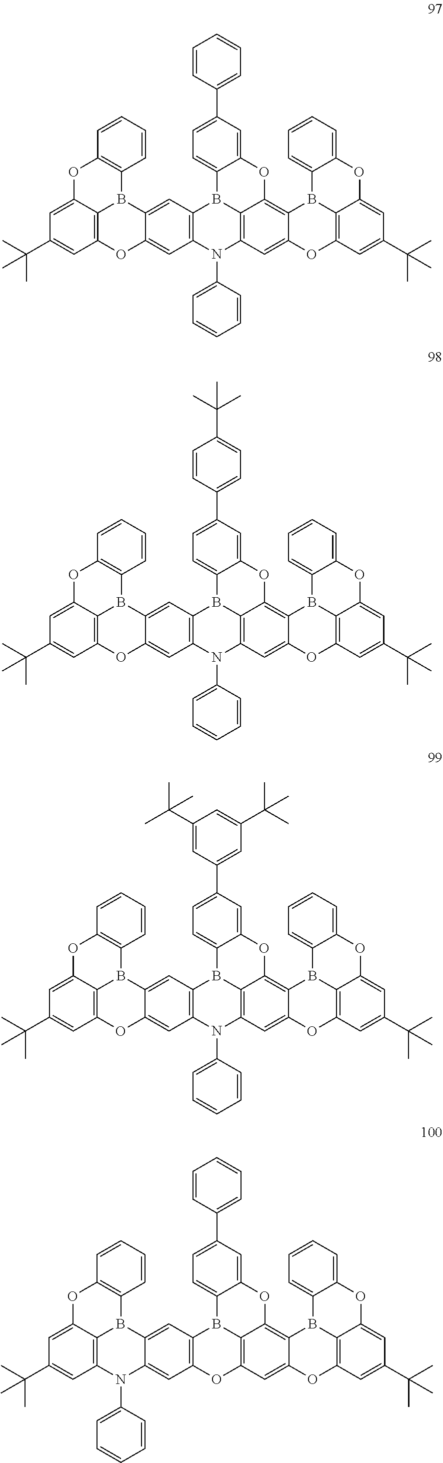

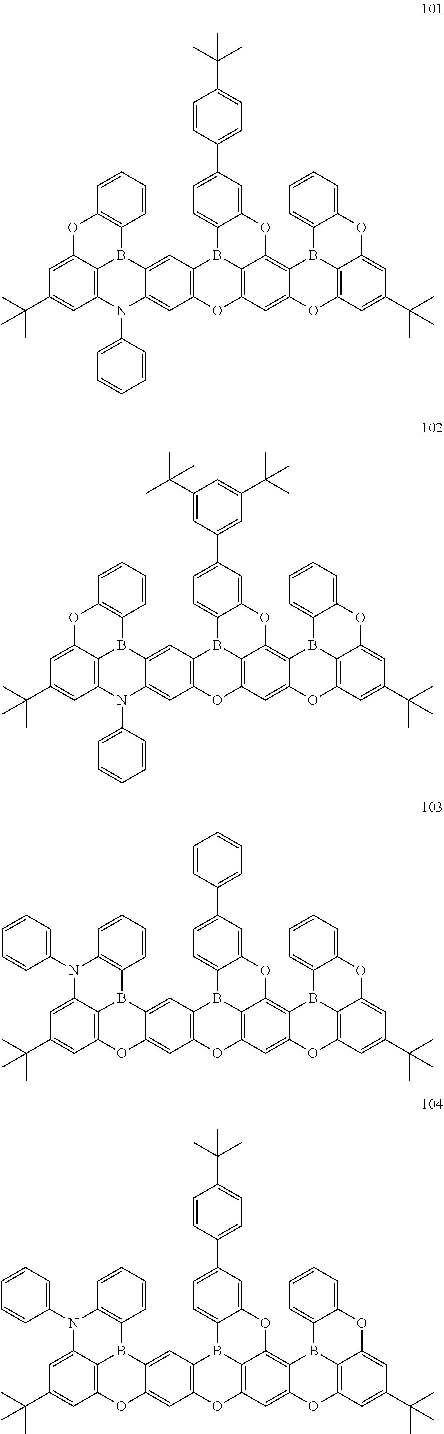

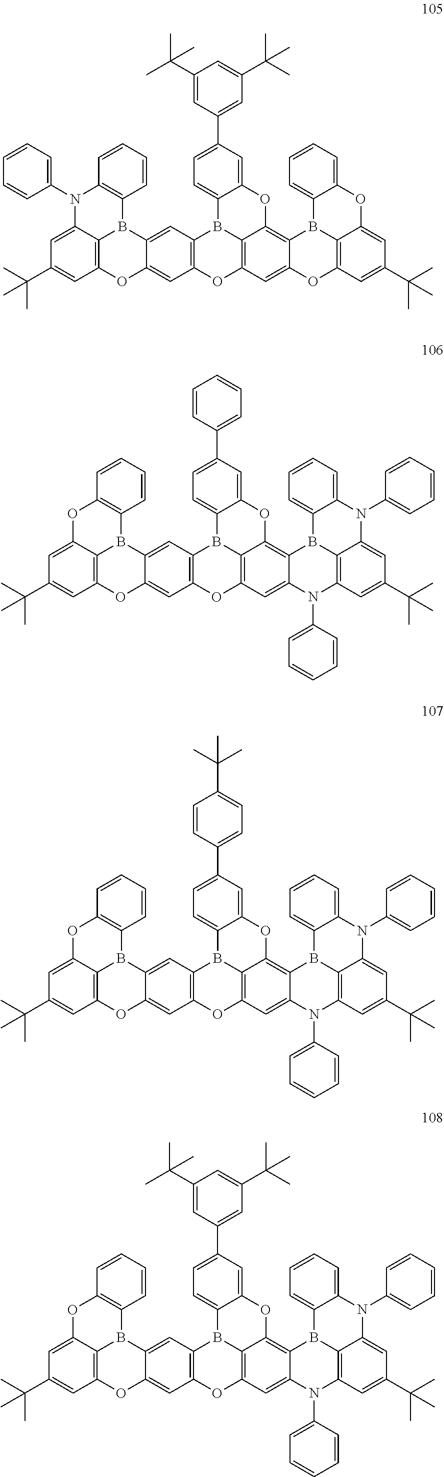

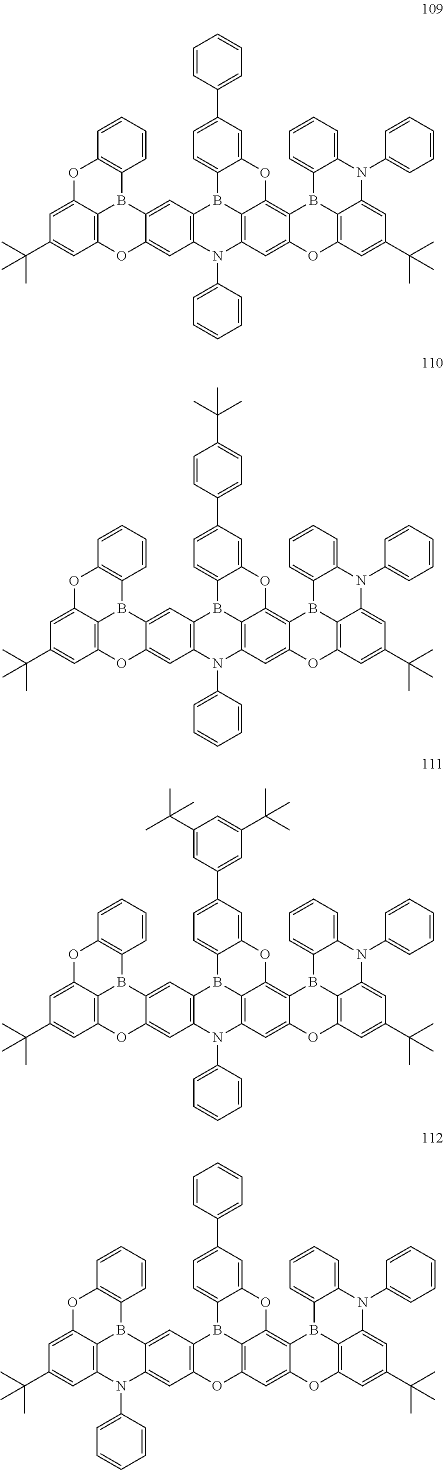

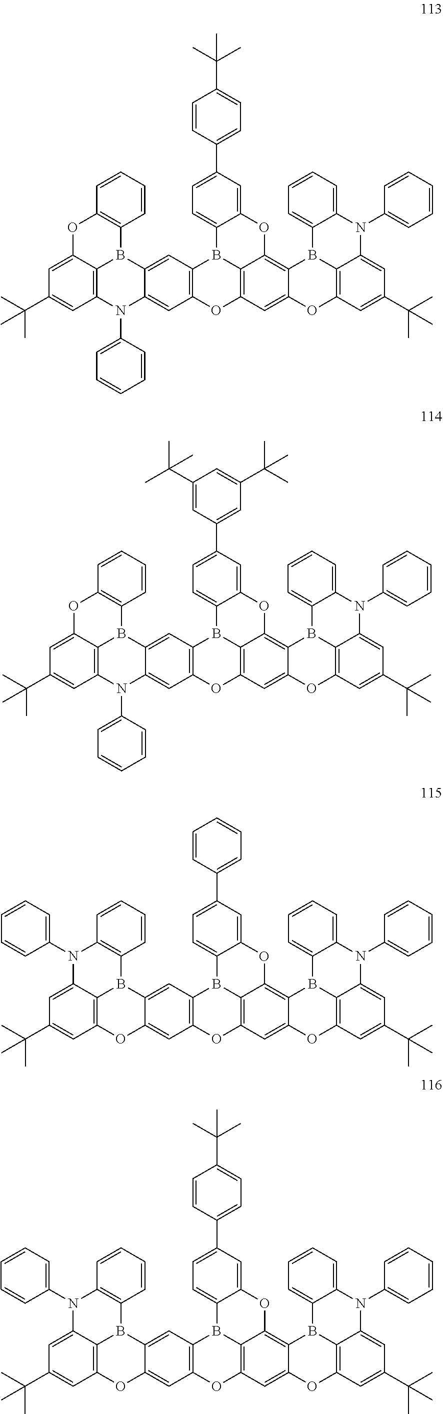

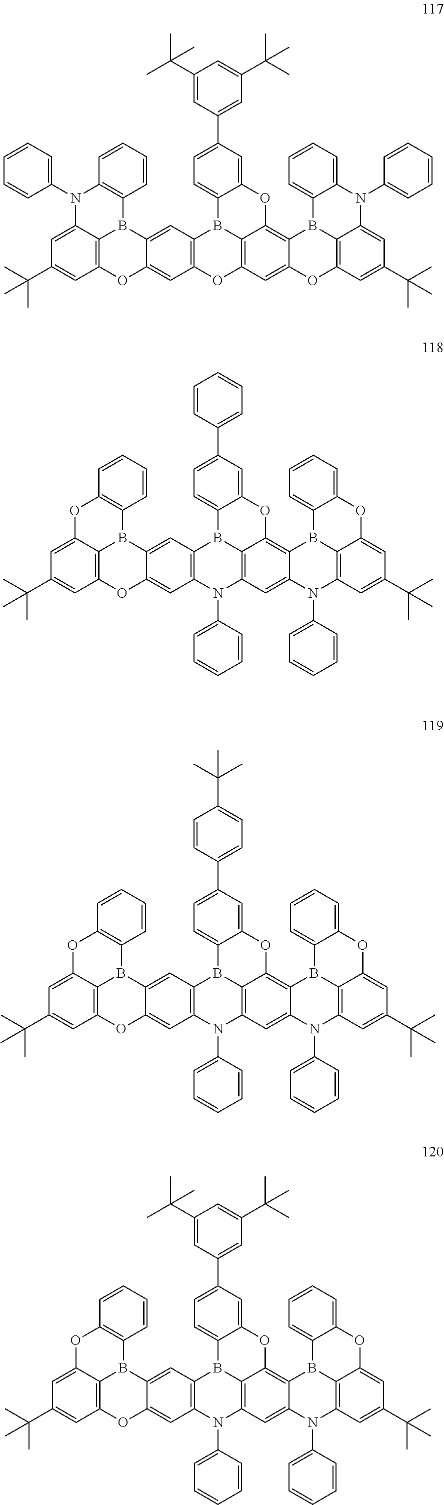

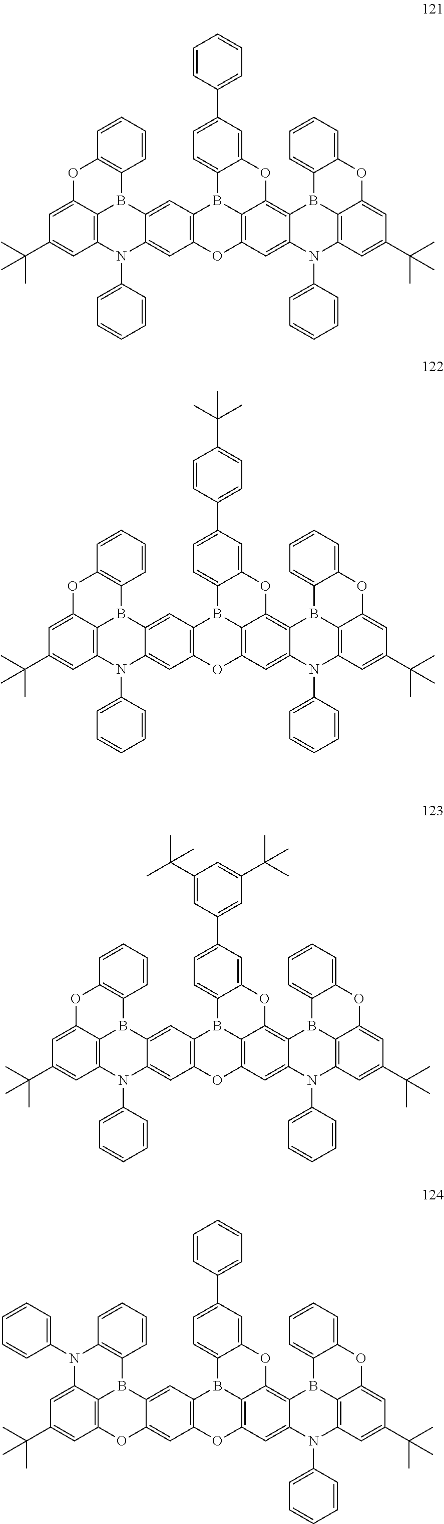

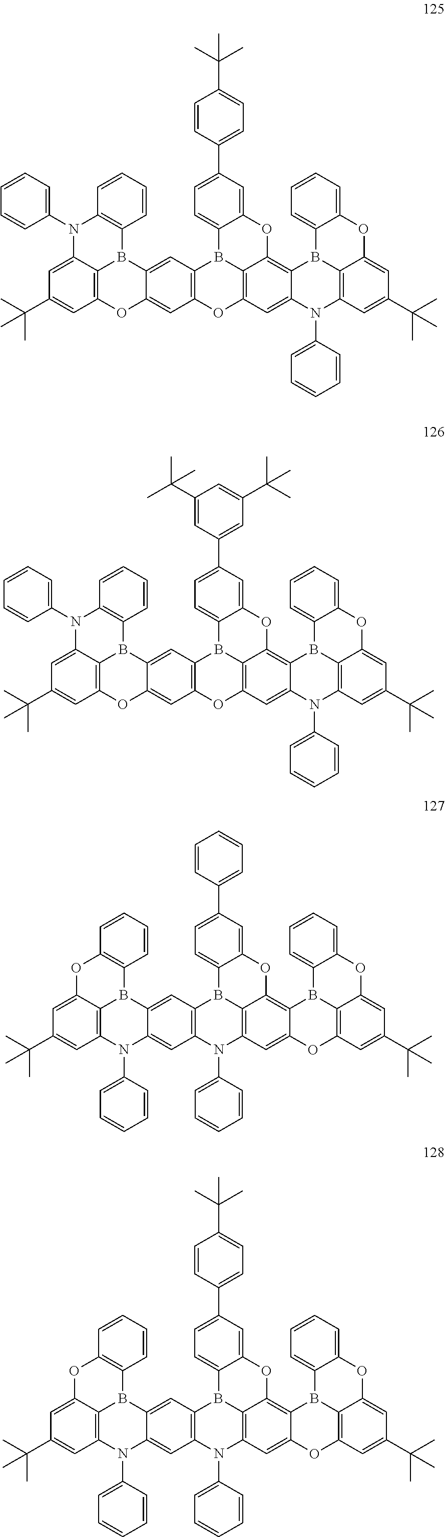

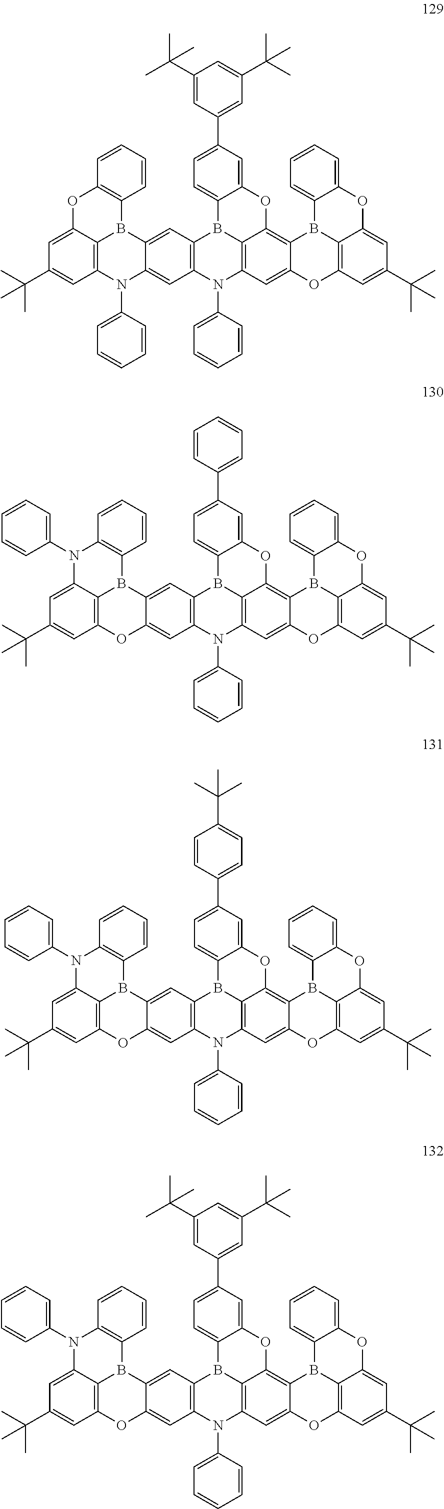

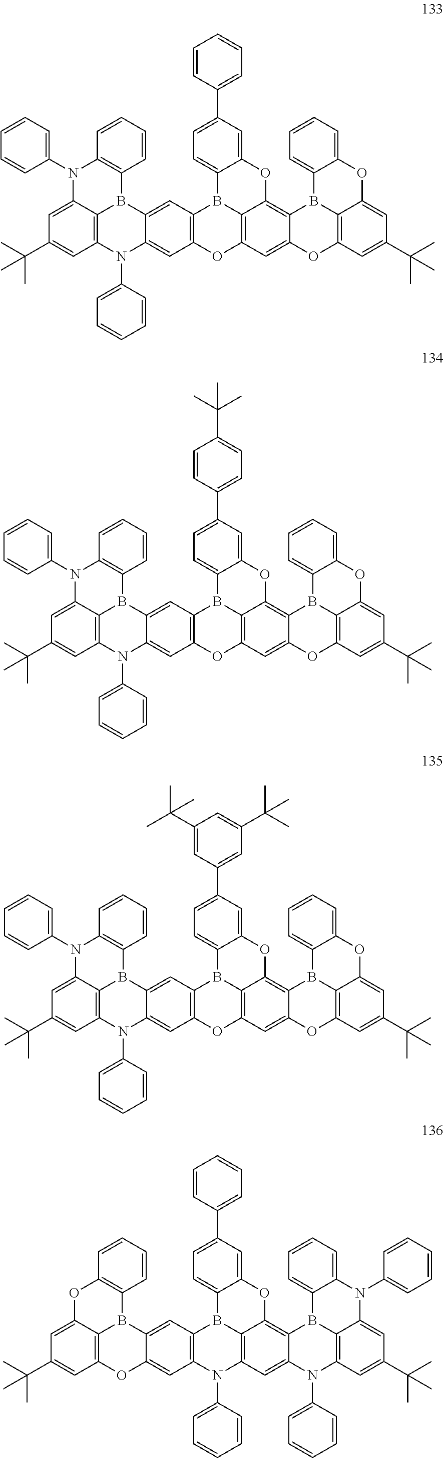

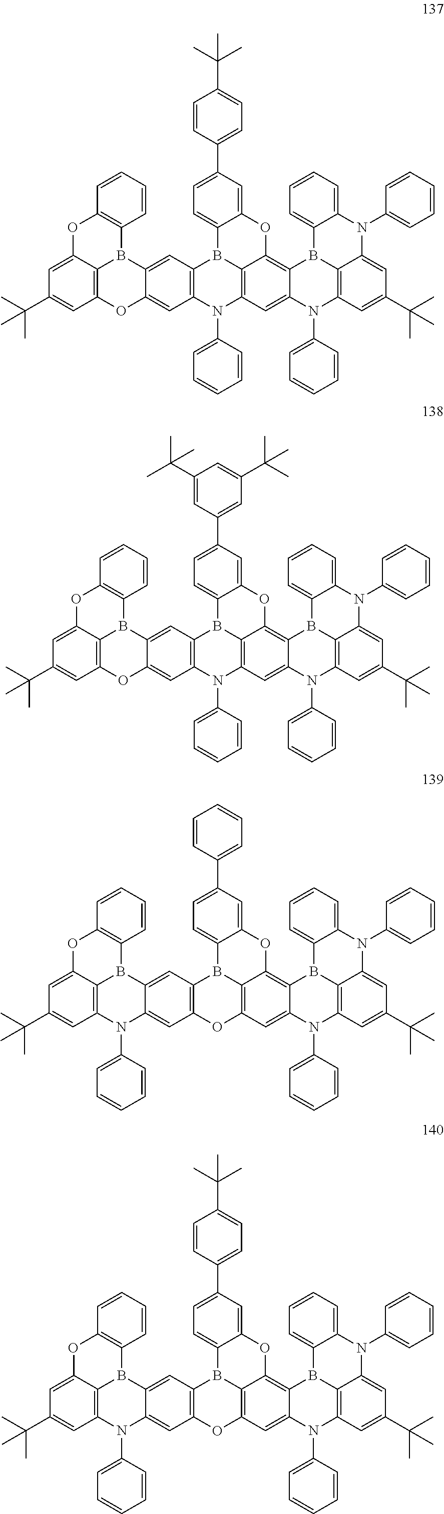

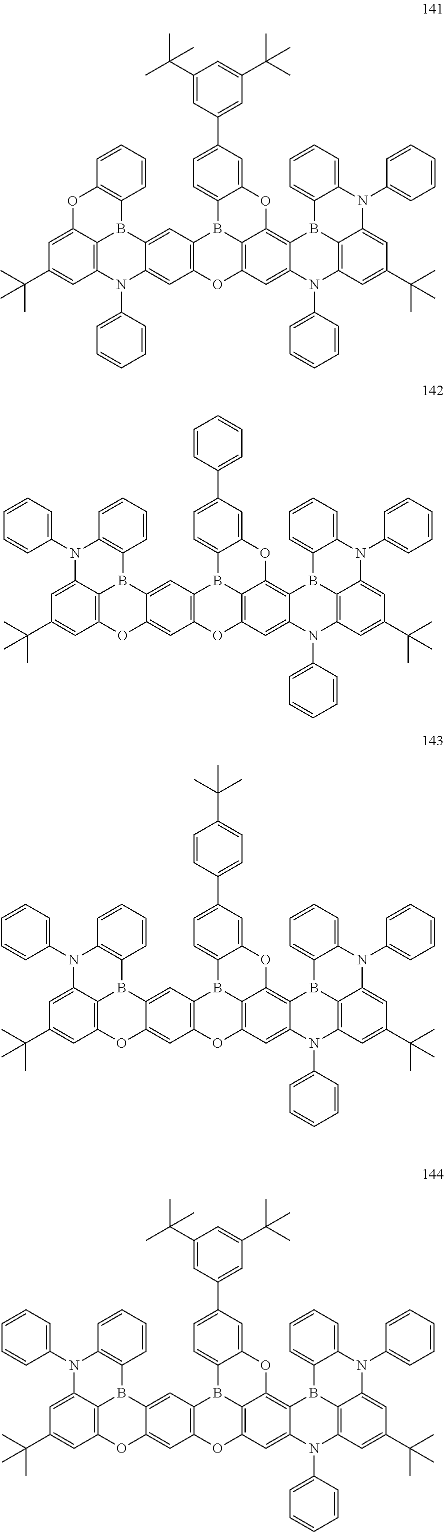

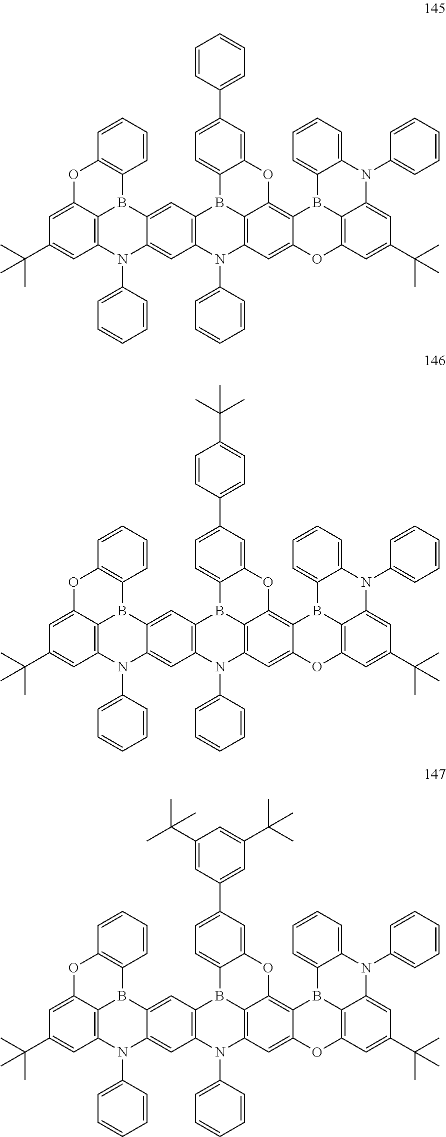 [SMILES: CC(C)(C)c1cc2c3c(c1)N(c1ccccc1)c1cc4c(cc1B3c1ccccc1O2)B1c2ccc(-c3ccccc3)cc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc(C(C)(C)C)c1]

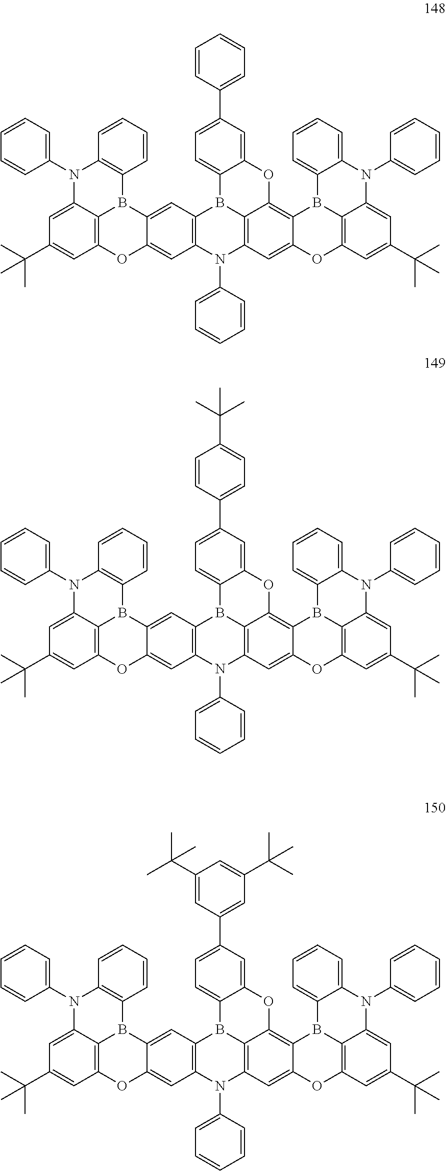 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)O2 ; CC(C)(C)c1ccc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1]

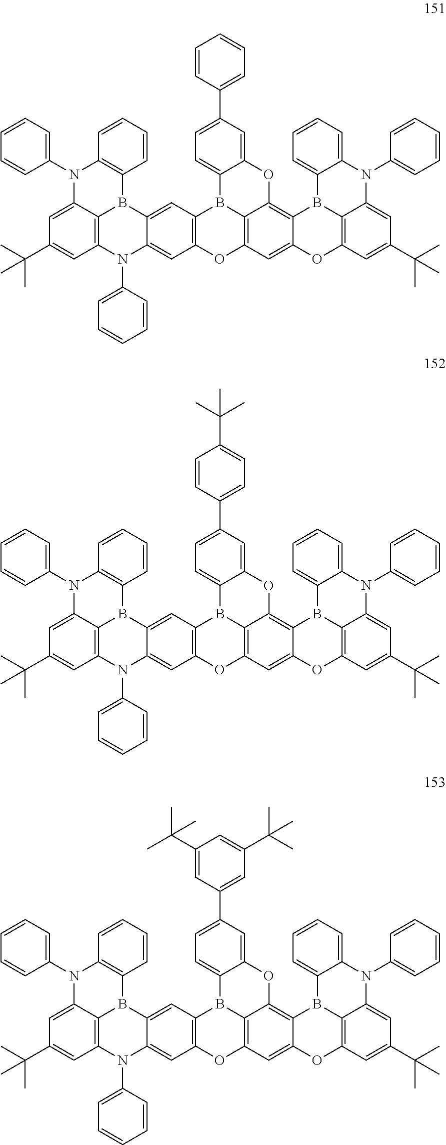 [SMILES: CC(C)(C)c1cc2c3c(c1)N(c1ccccc1)c1ccccc1B3c1c(cc3c4c1Oc1cc(-c5ccccc5)ccc1B4c1cc4c(cc1O3)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc(C(C)(C)C)c1]

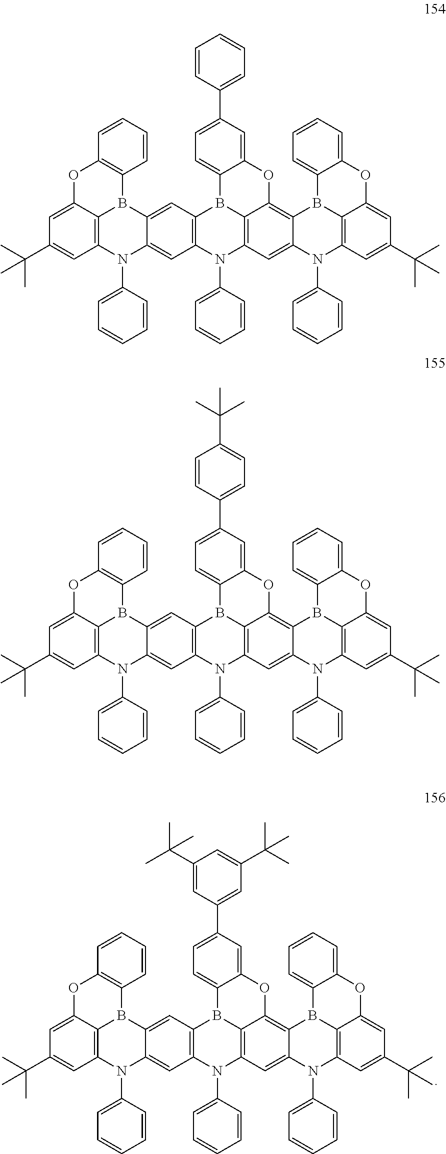

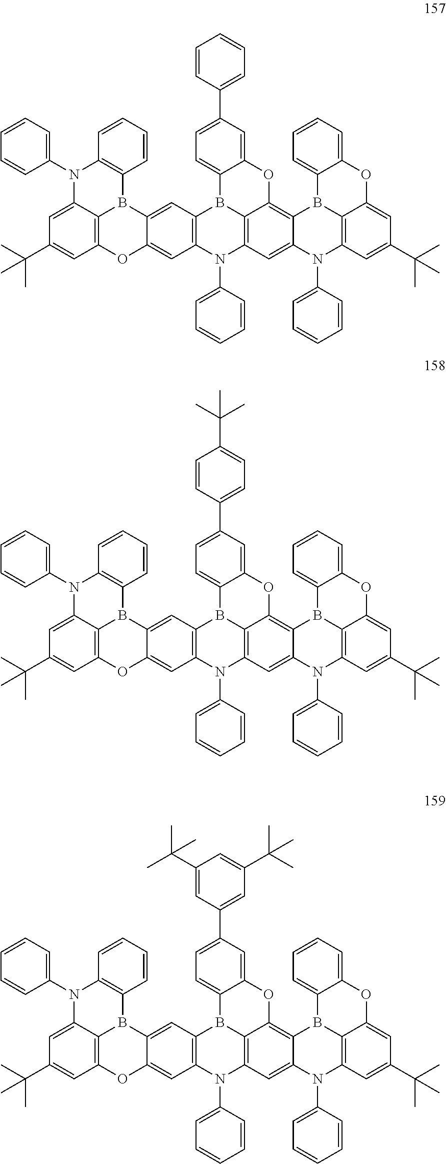

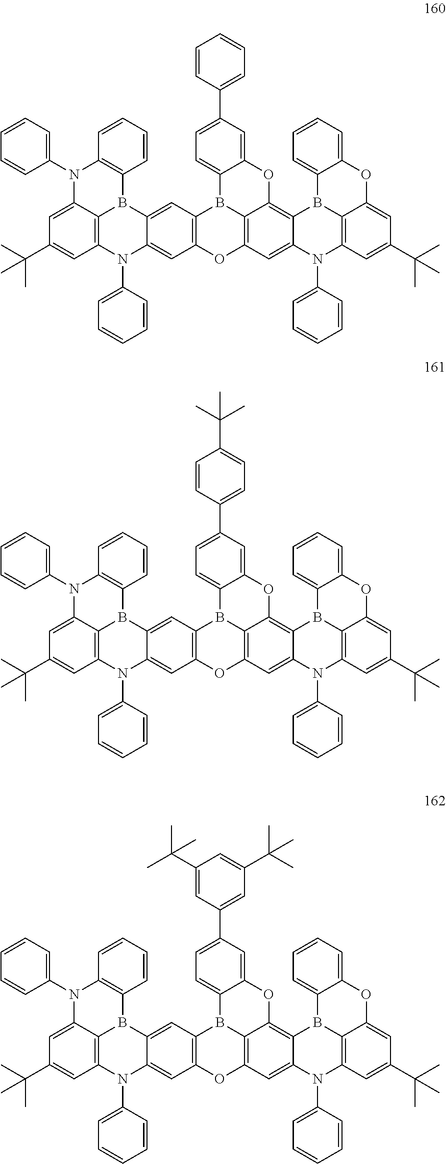

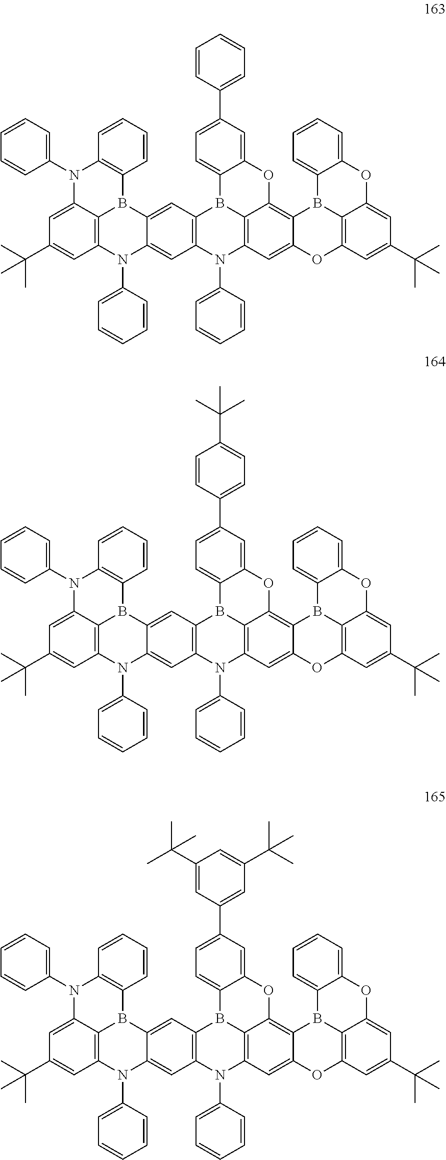

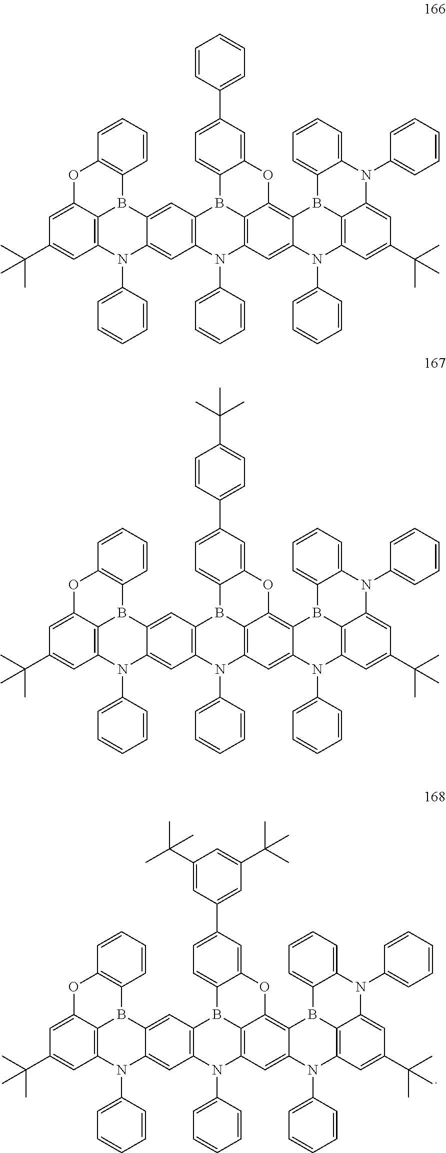 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc(C(C)(C)C)c1]

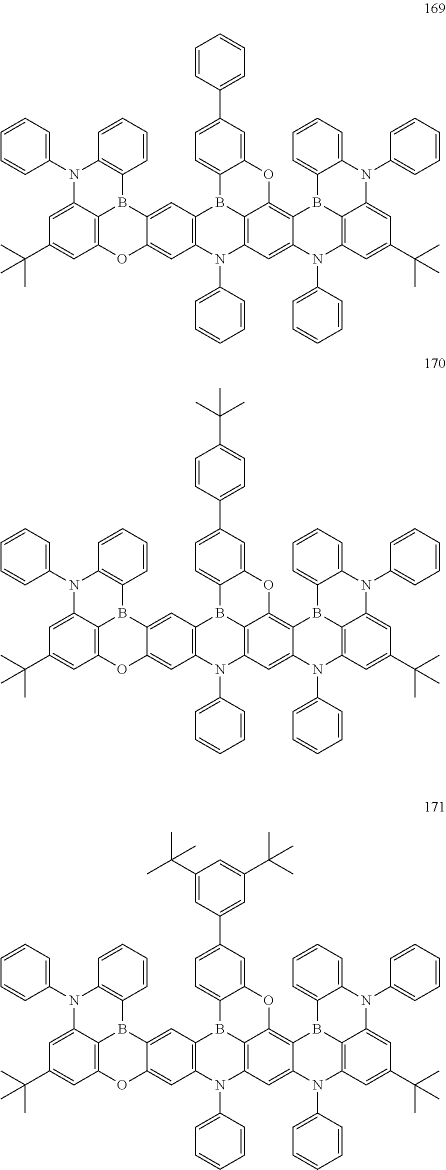 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)N2c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc(C(C)(C)C)c1]

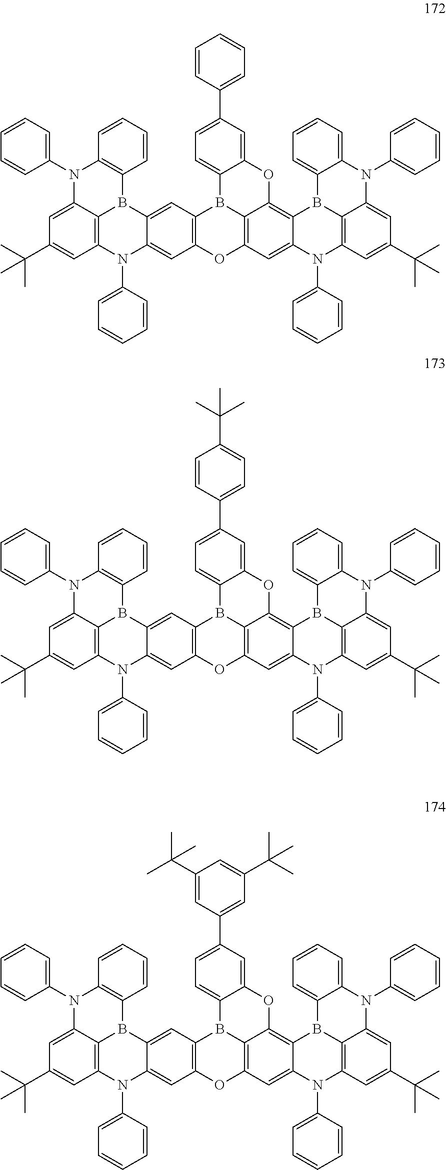 [SMILES: CC(C)(C)c1cc2c3c(c1)N(c1ccccc1)c1cc4c(cc1B3c1ccccc1N2c1ccccc1)B1c2ccc(-c3ccccc3)cc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc(C(C)(C)C)c1]

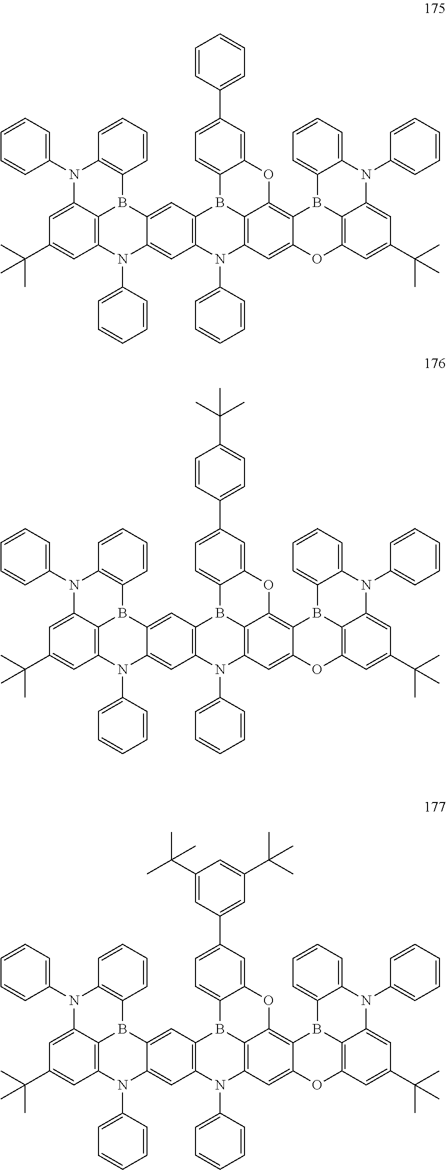 [SMILES: CC(C)(C)c1cc2c3c(c1)N(c1ccccc1)c1ccccc1B3c1c(cc3c4c1Oc1cc(-c5ccccc5)ccc1B4c1cc4c(cc1N3c1ccccc1)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1]

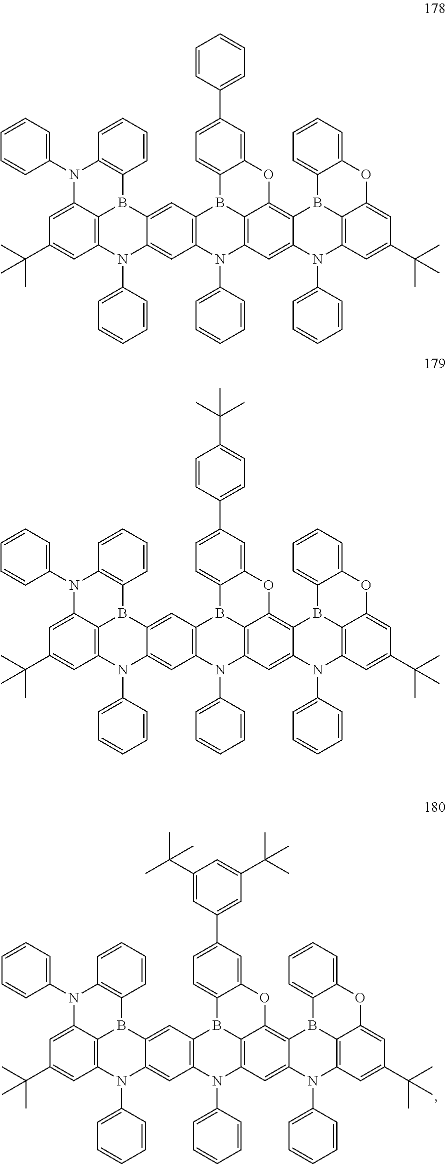

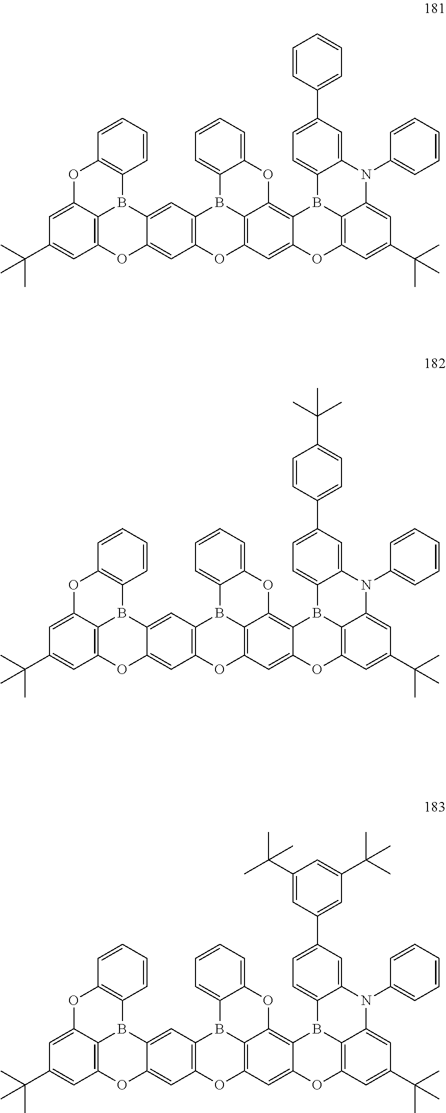 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc(C(C)(C)C)c1]

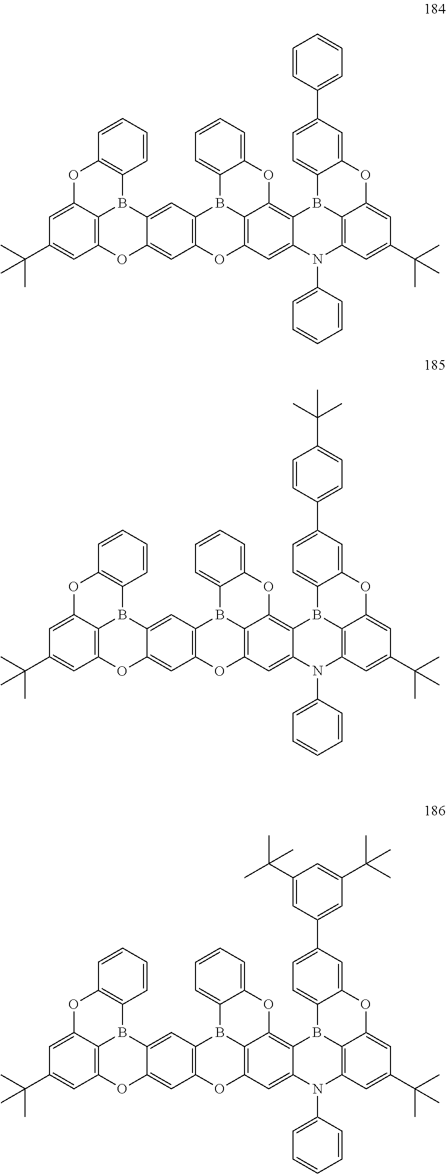

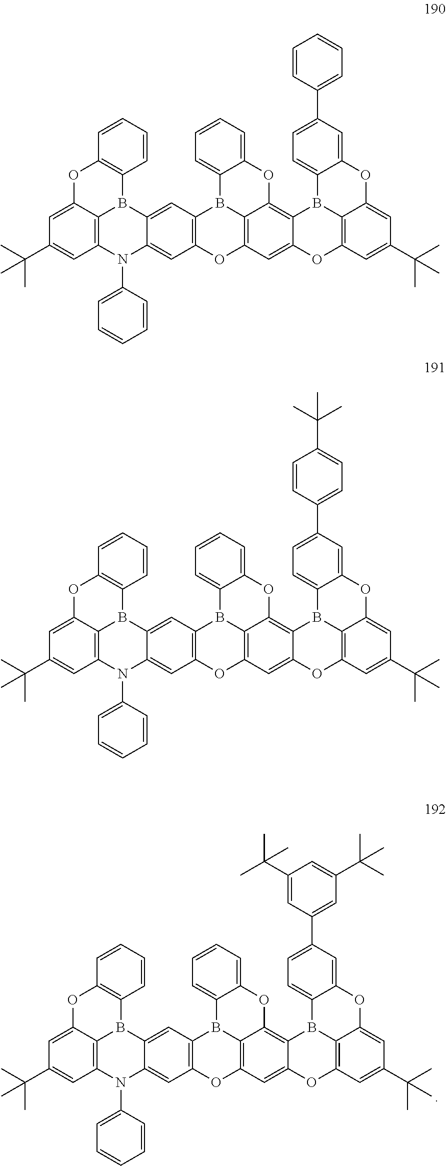

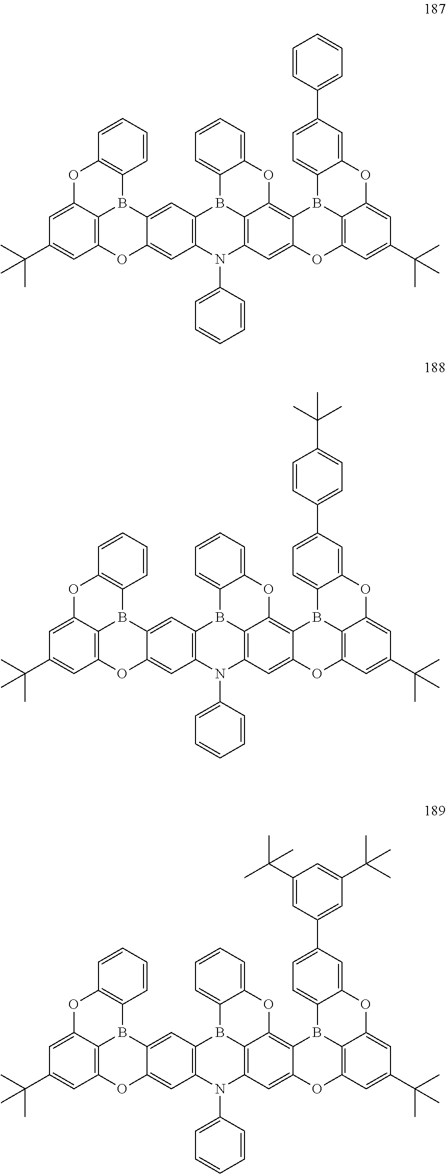

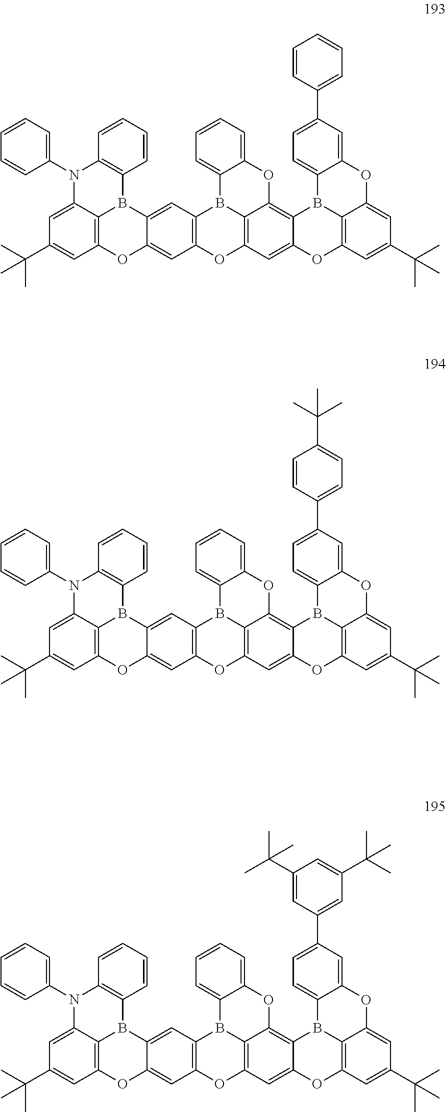

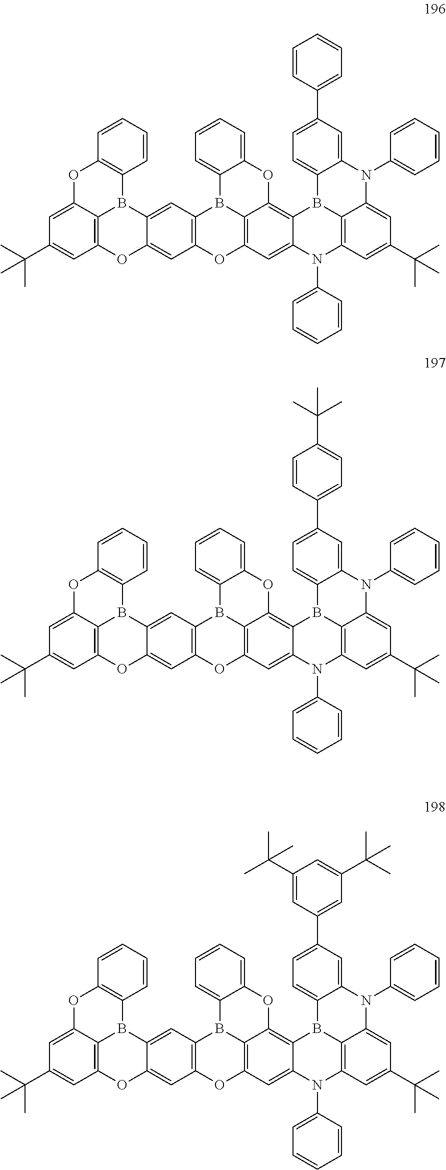 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)N1c1ccccc1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc(C(C)(C)C)c1]

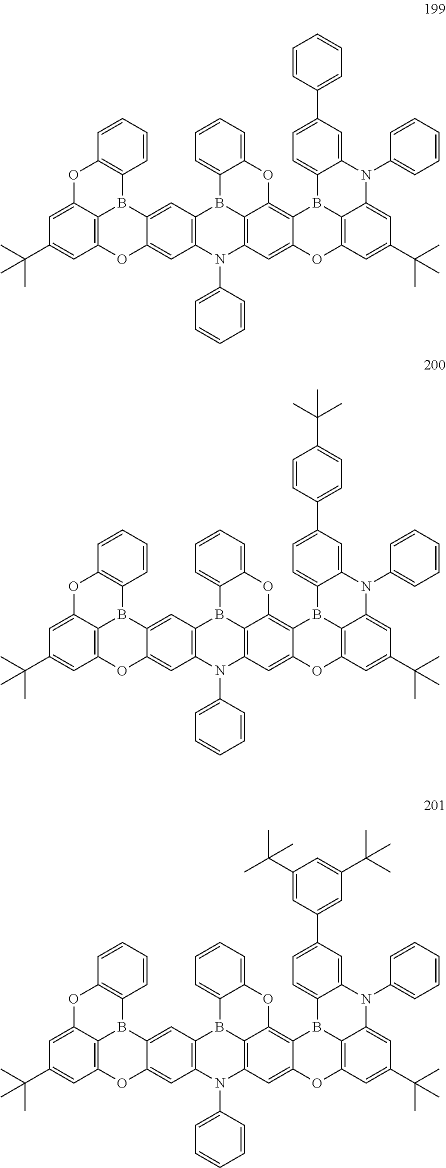 [SMILES: CC(C)(C)c1cc2c3c(c1)Oc1cc4c(cc1B3c1ccccc1O2)B1c2ccccc2Oc2c3c(cc(c21)N4c1ccccc1)Oc1cc(C(C)(C)C)cc2c1B3c1ccc(-c3ccccc3)cc1N2c1ccccc1 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc(C(C)(C)C)c1]

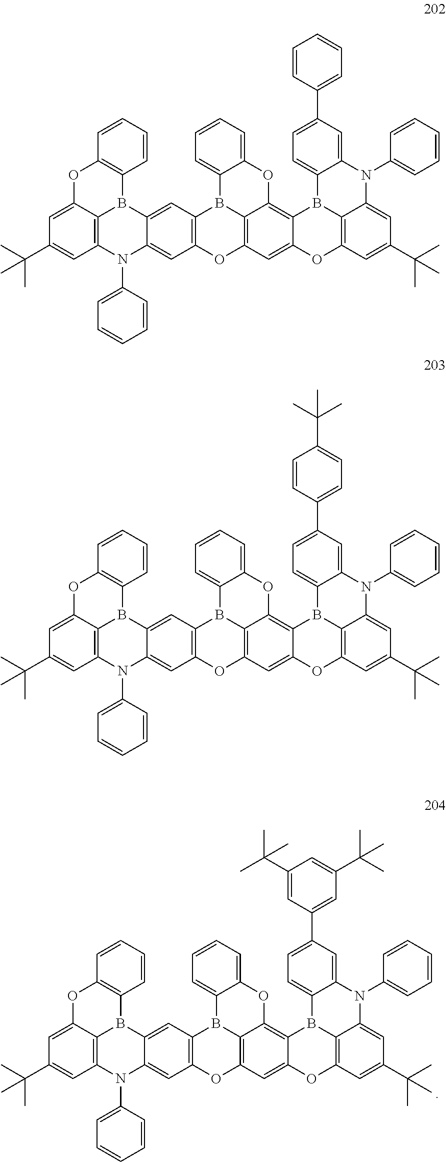 [SMILES: CC(C)(C)c1cc2c3c(c1)N(c1ccccc1)c1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc(C(C)(C)C)c1]

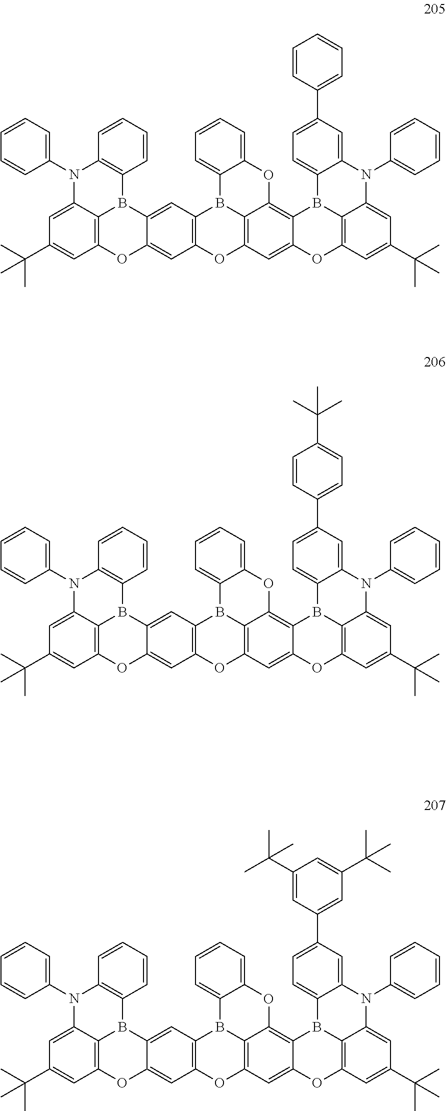 [SMILES: CC(C)(C)c1cc2c3c(c1)N(c1ccccc1)c1ccccc1B3c1cc3c(cc1O2)Oc1cc2c(c4c1B3c1ccccc1O4)B1c3ccc(-c4ccccc4)cc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc(C(C)(C)C)c1]

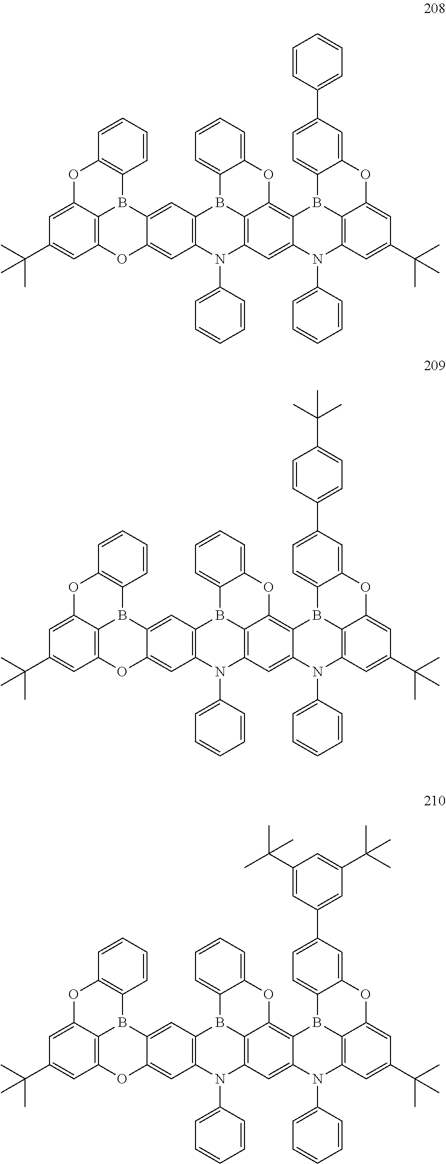

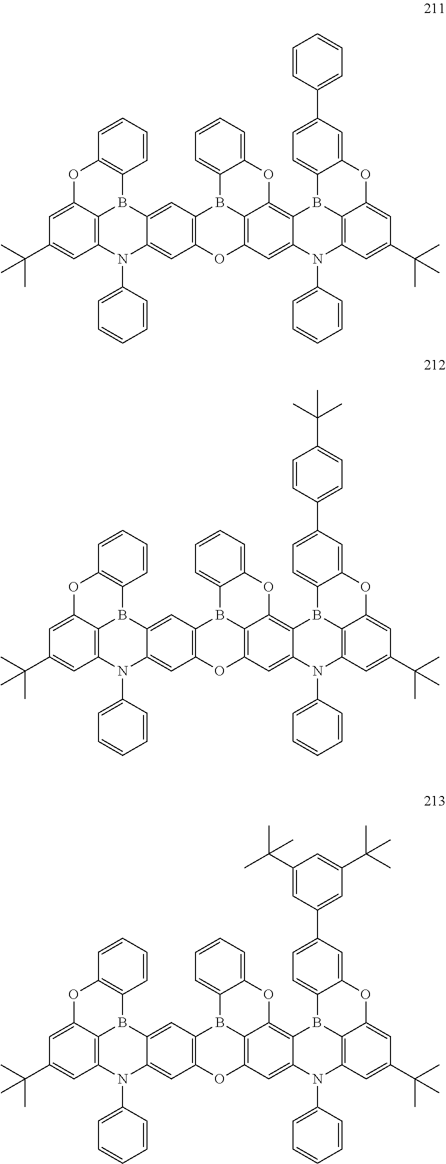

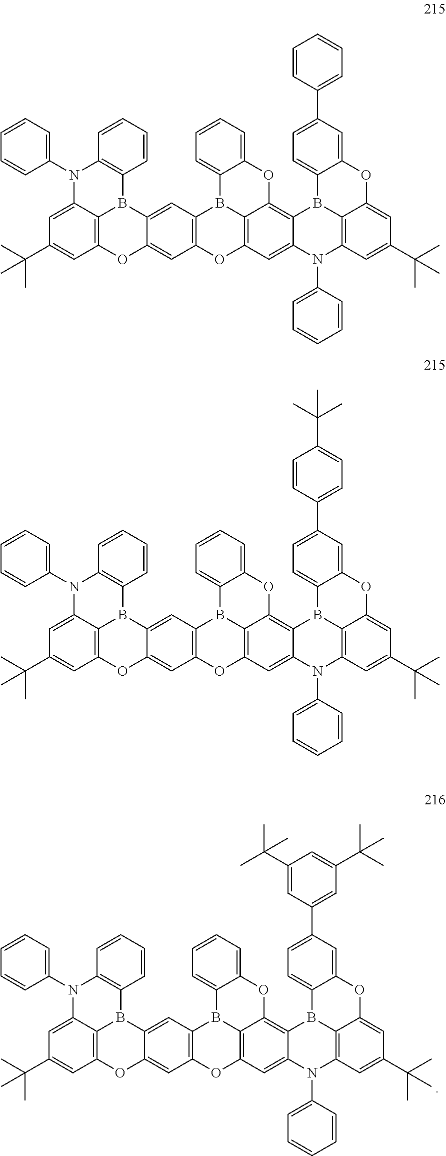

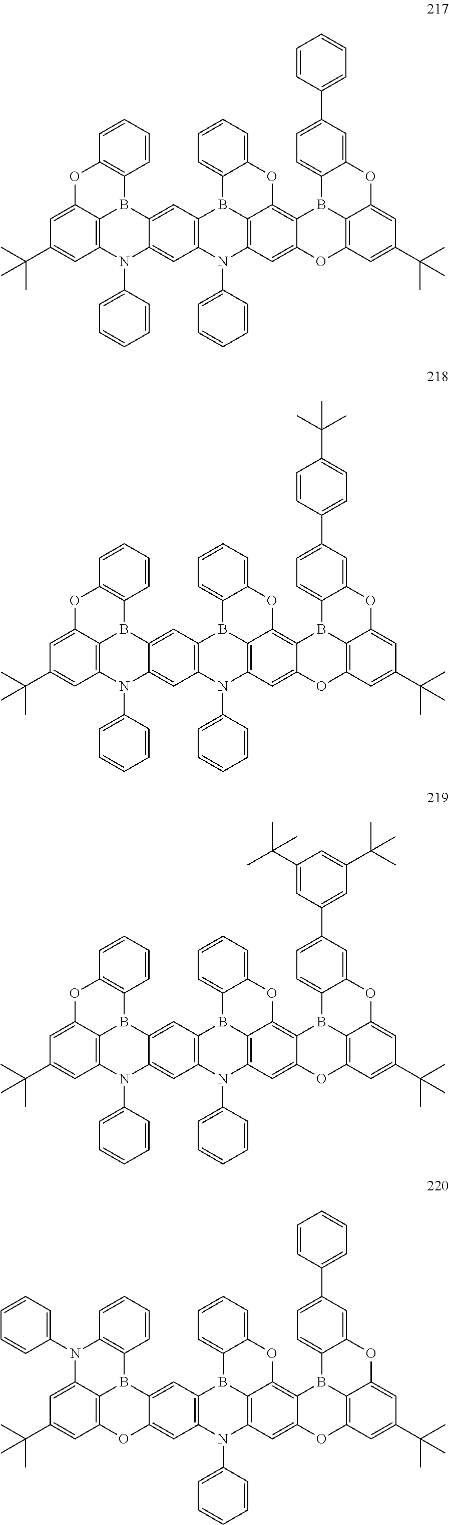

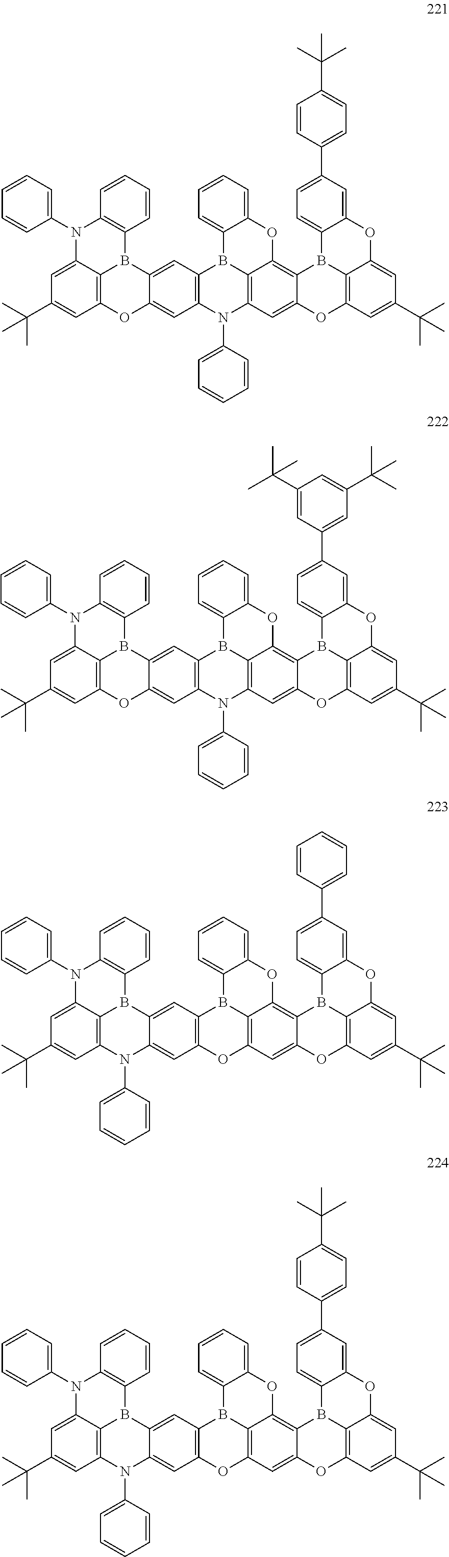

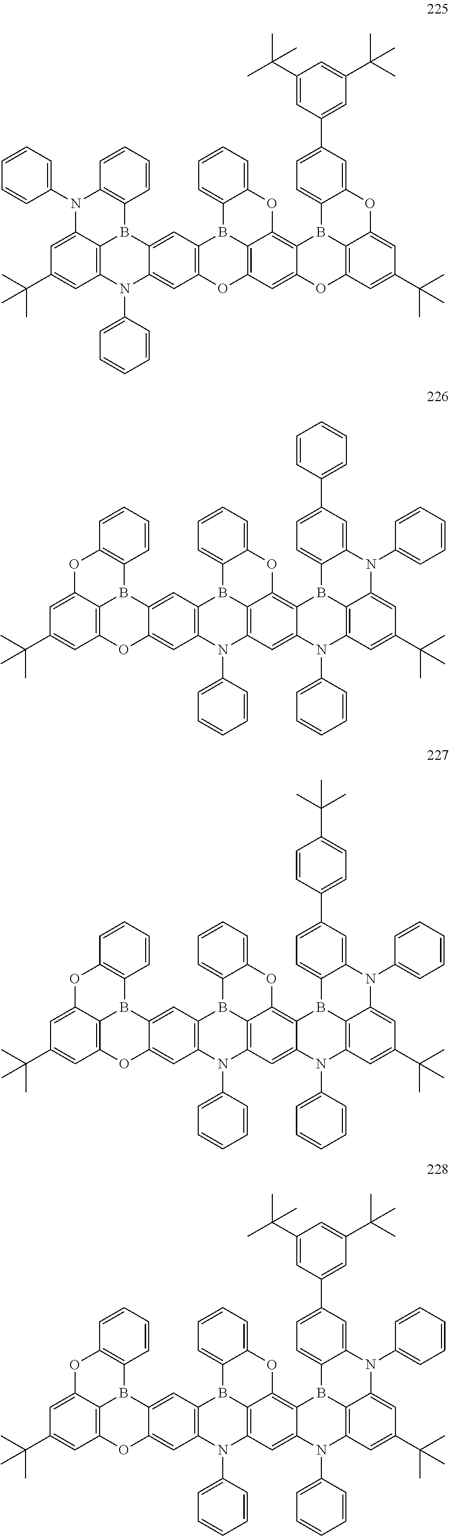

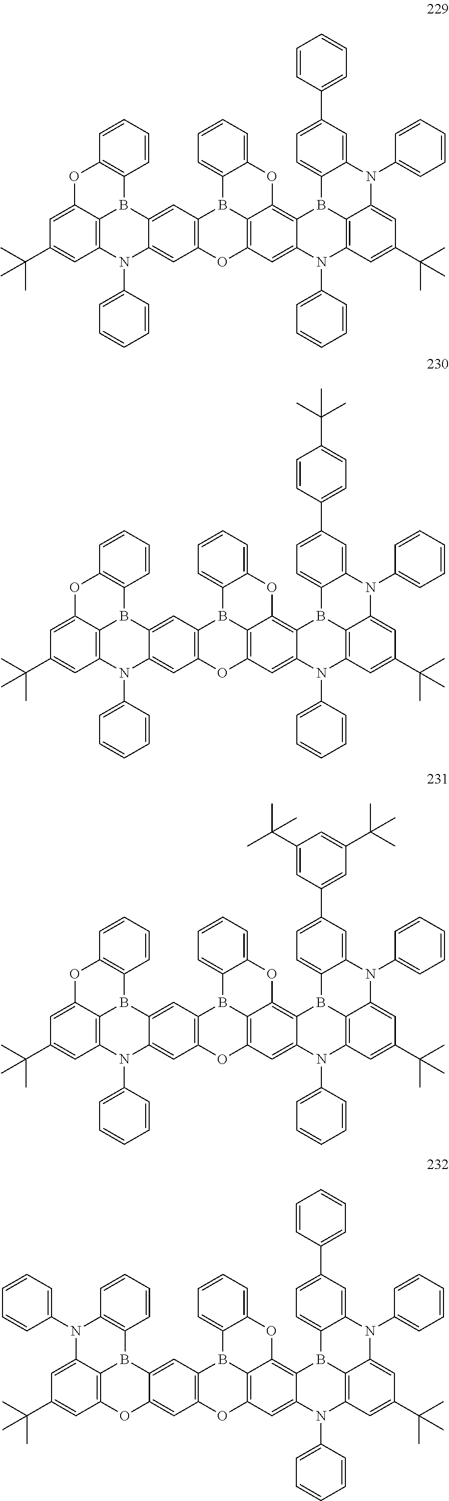

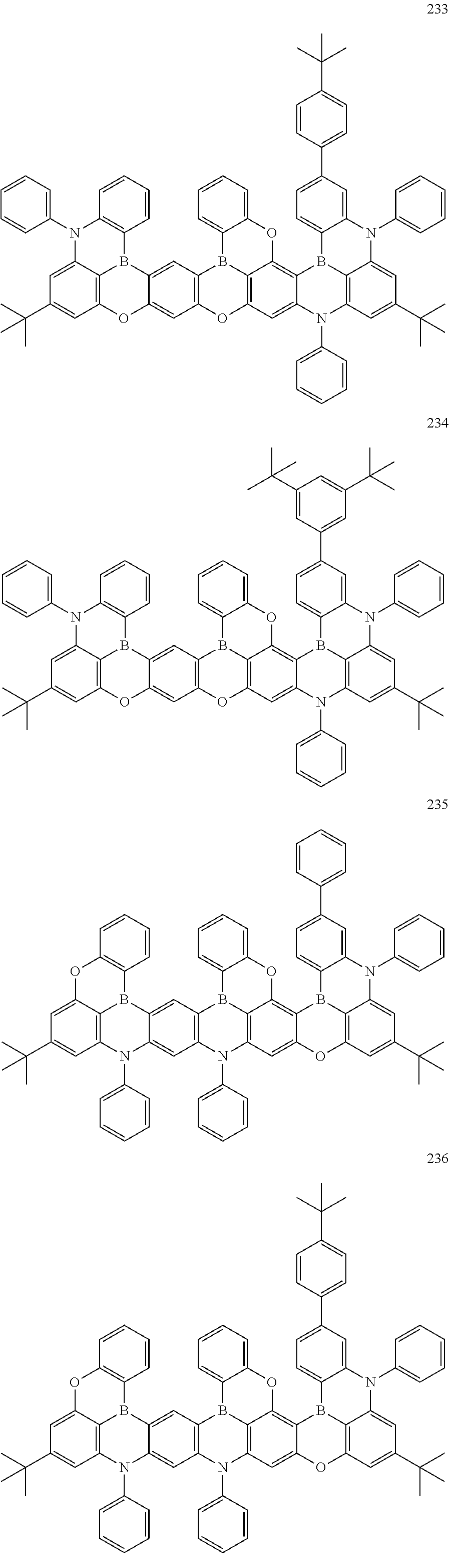

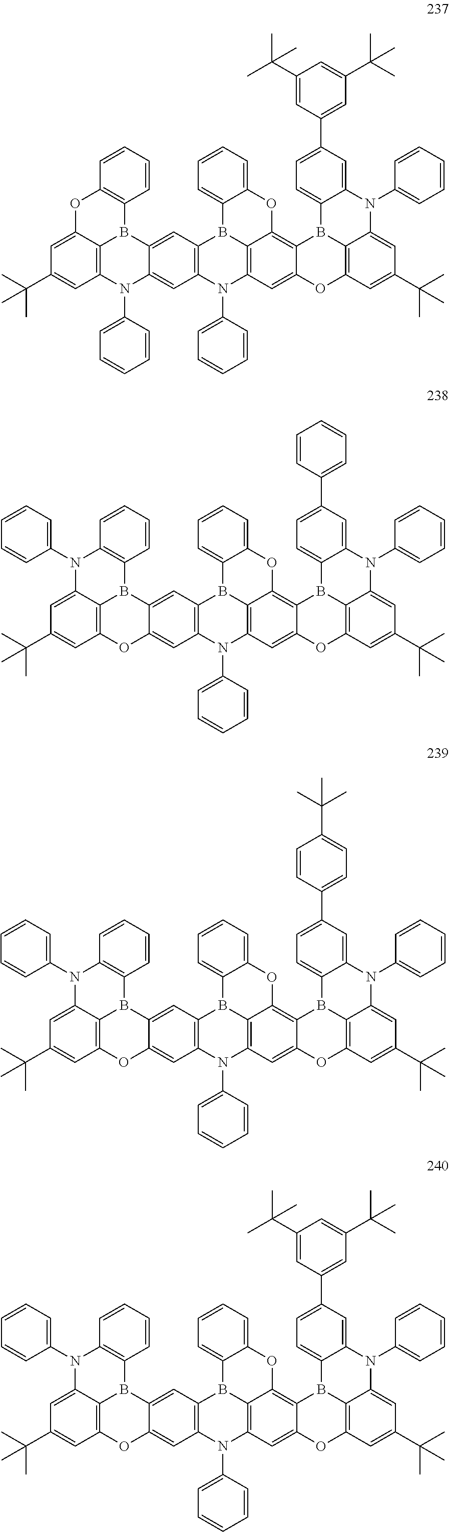

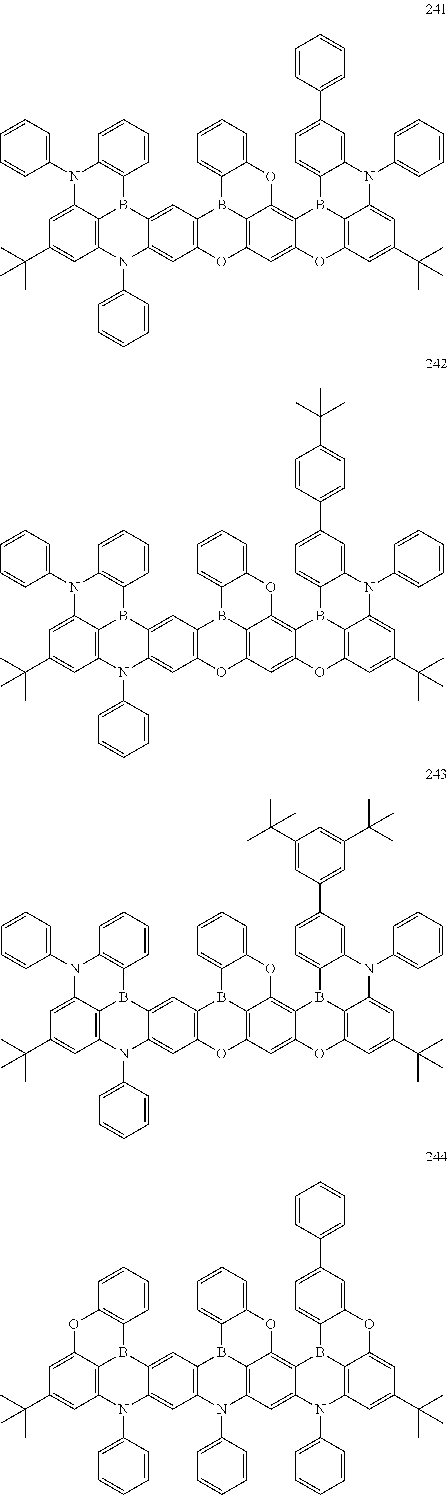

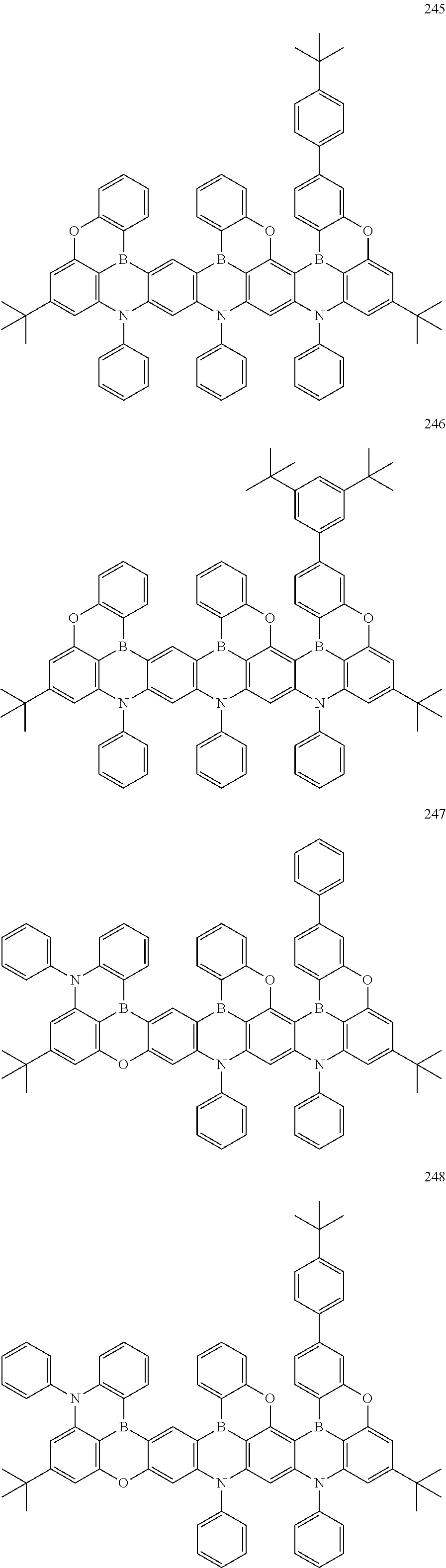

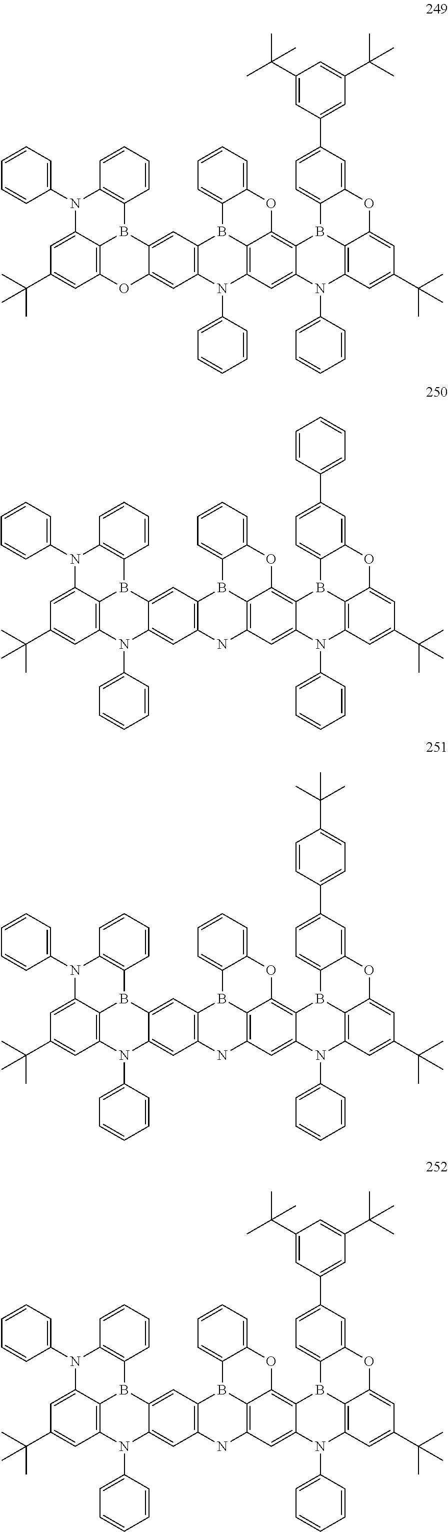

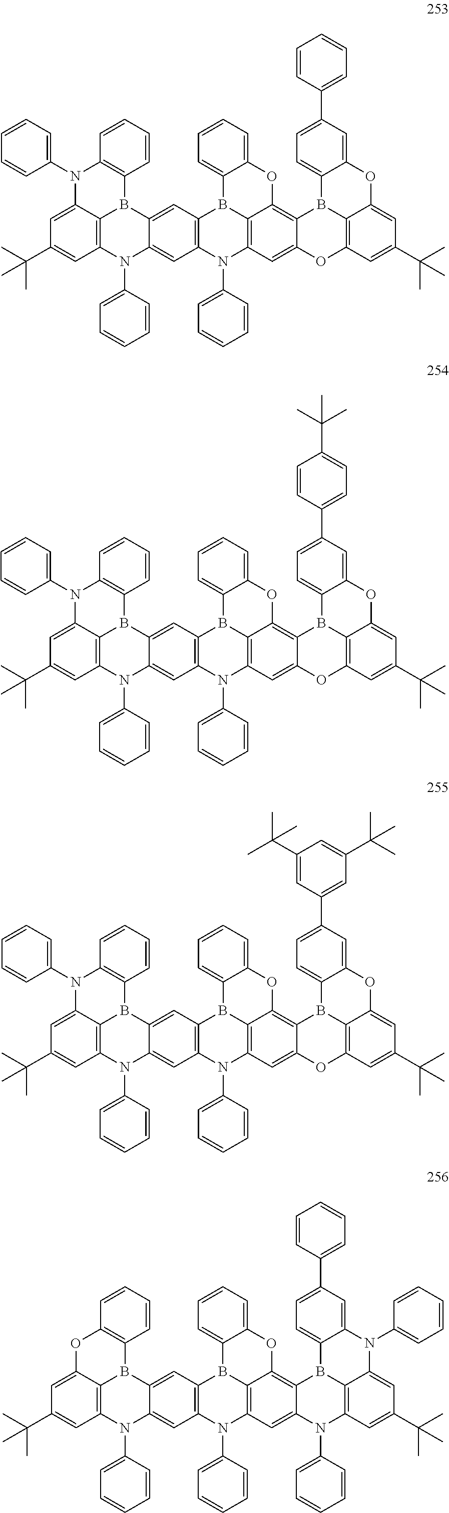

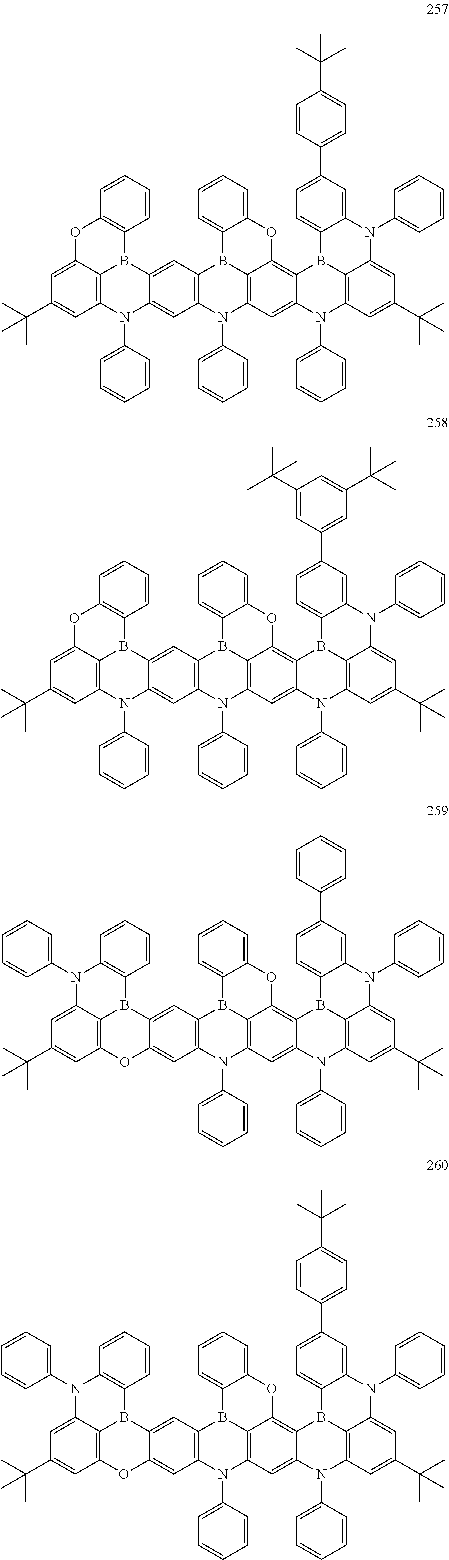

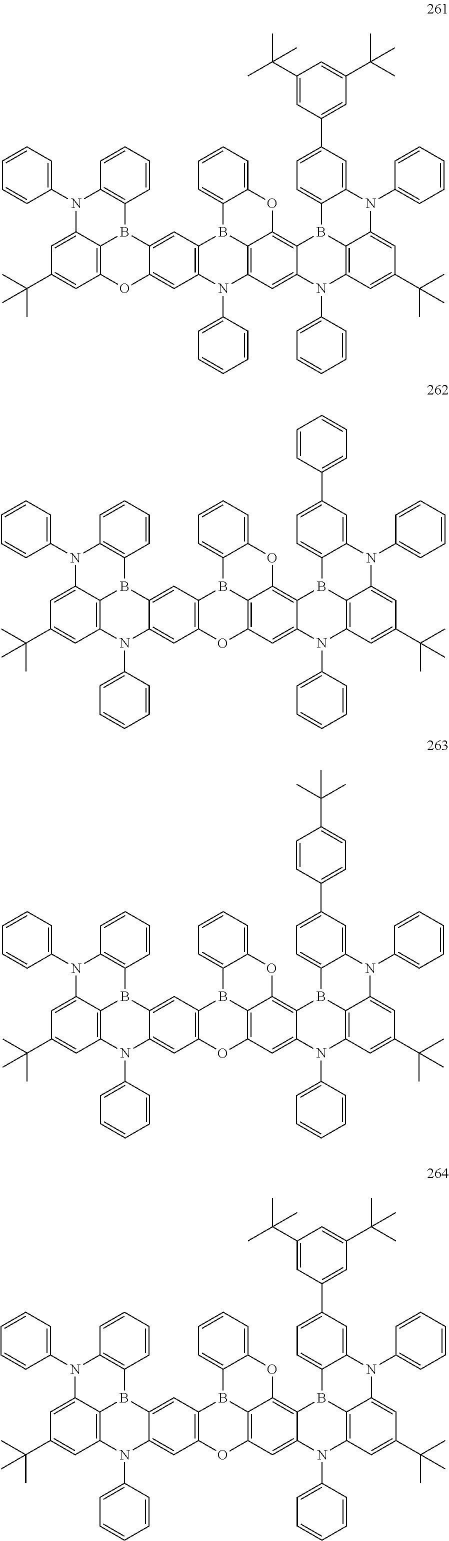

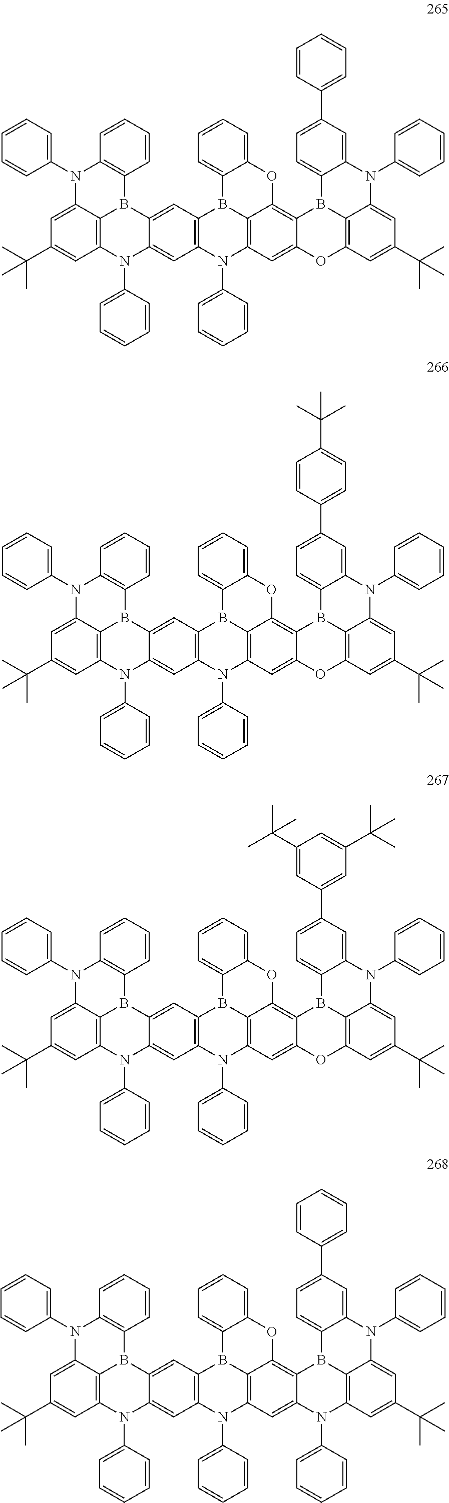

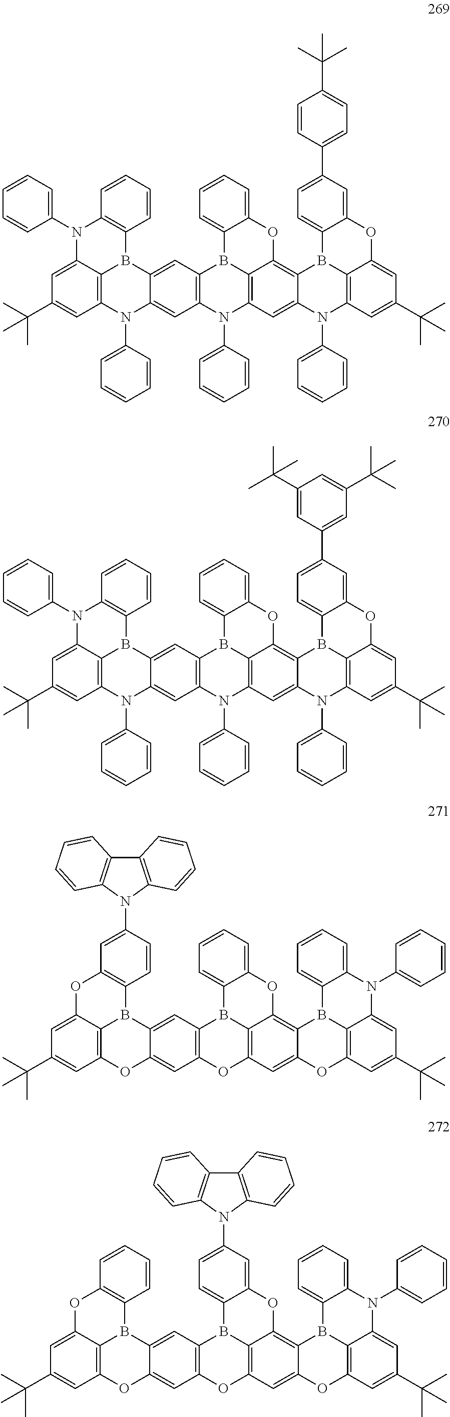

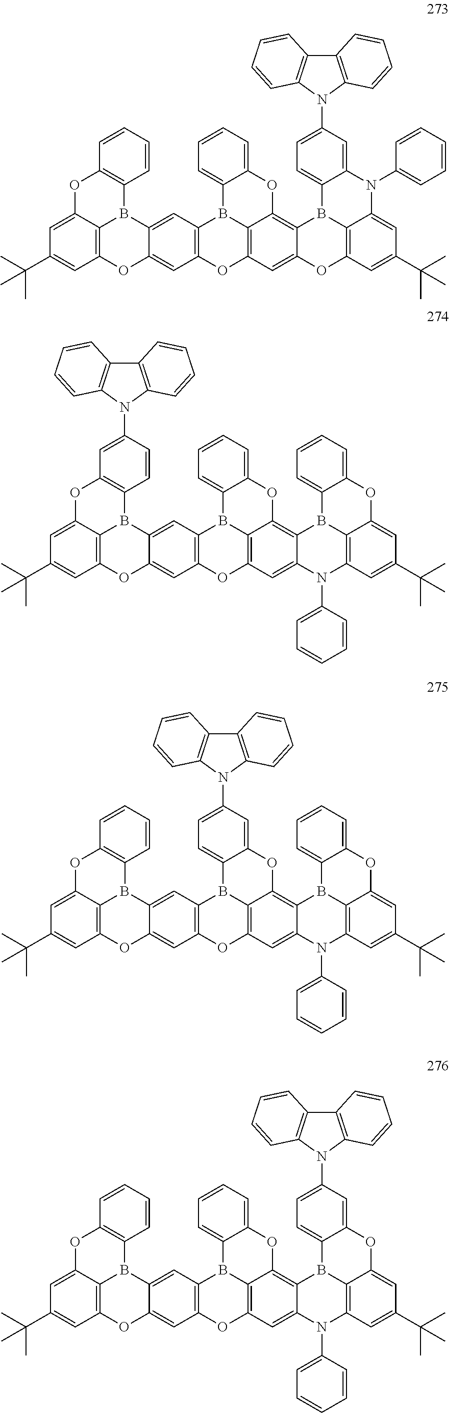

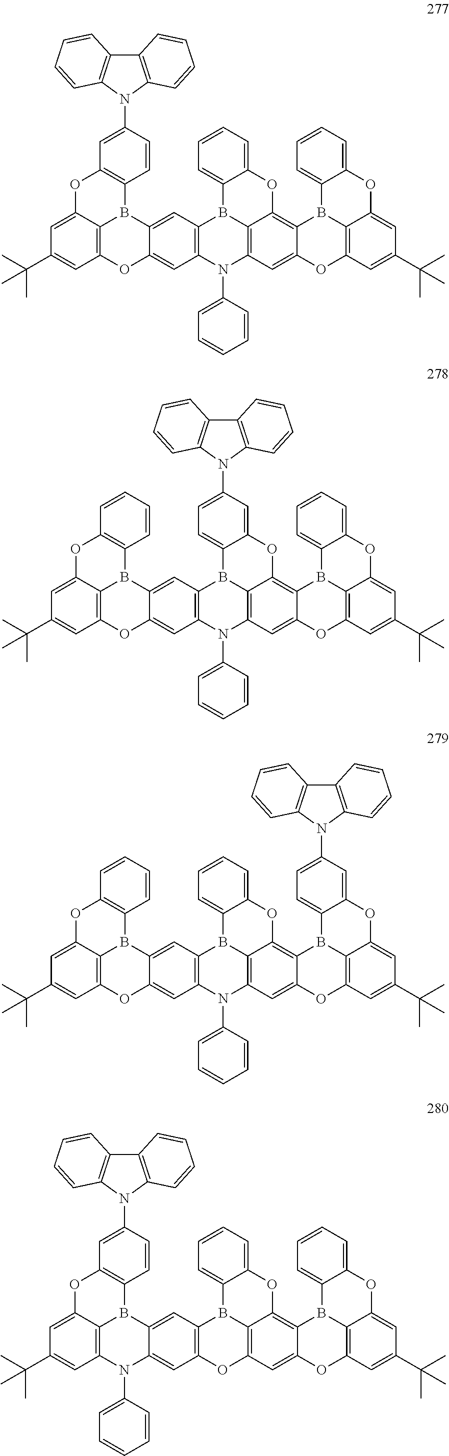

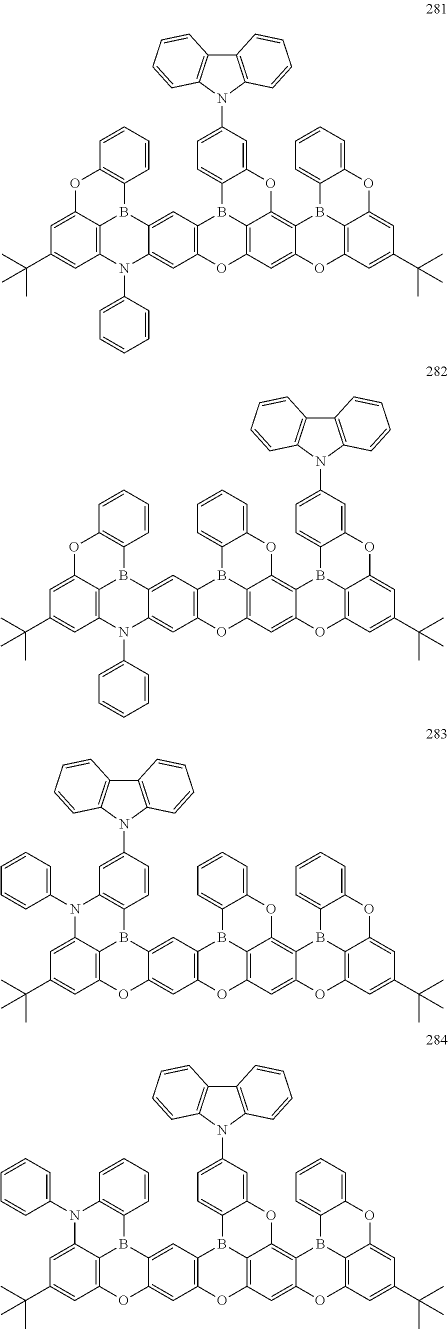

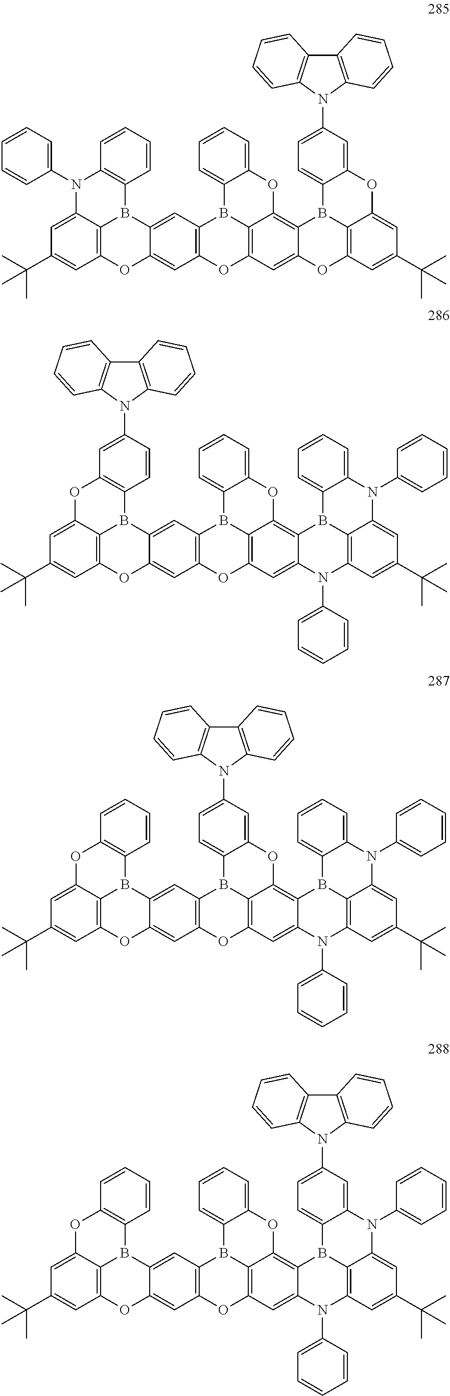

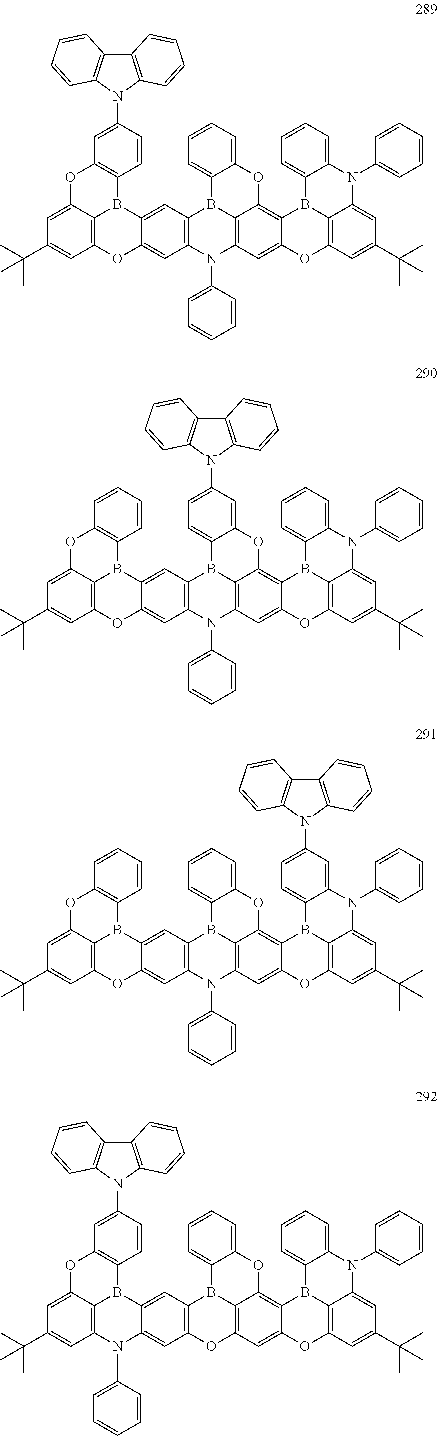

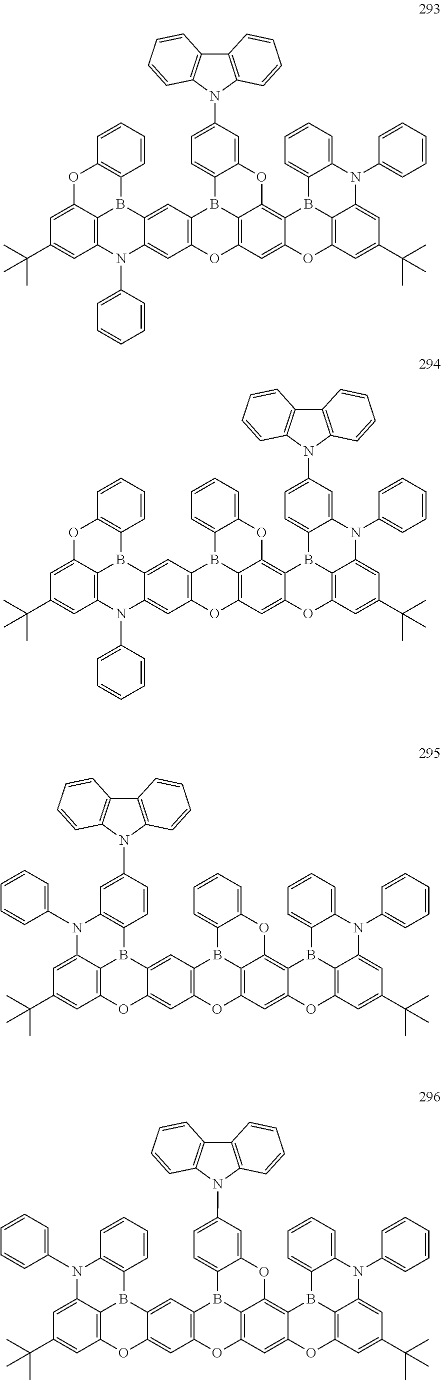

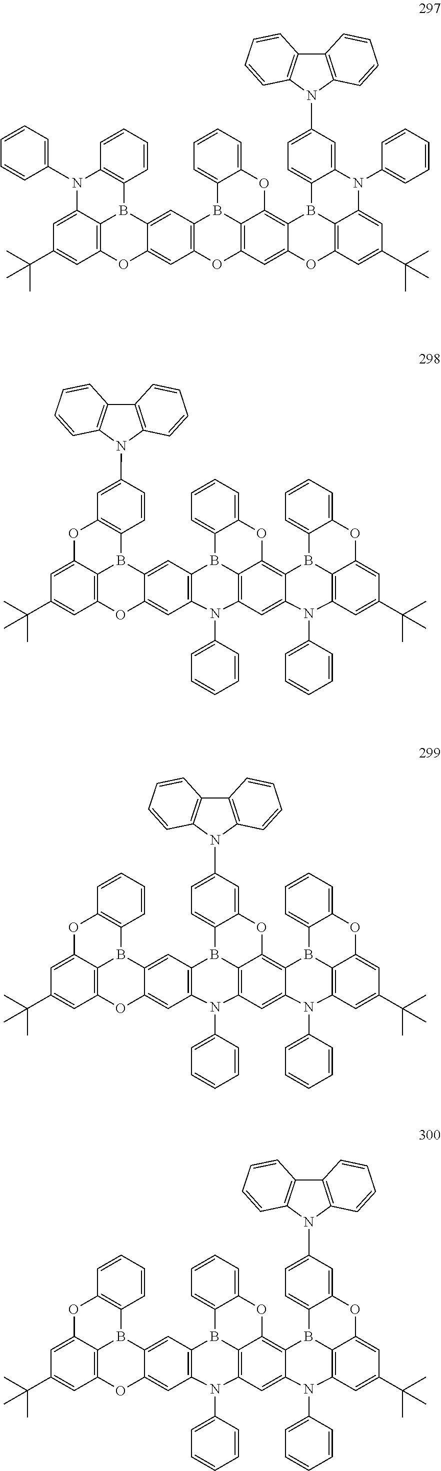

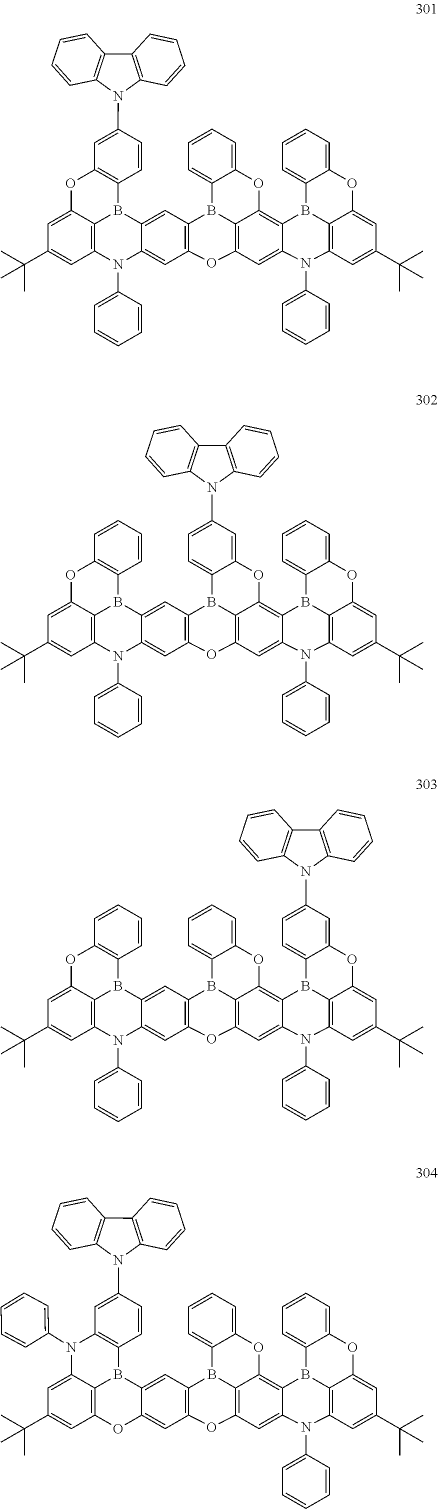

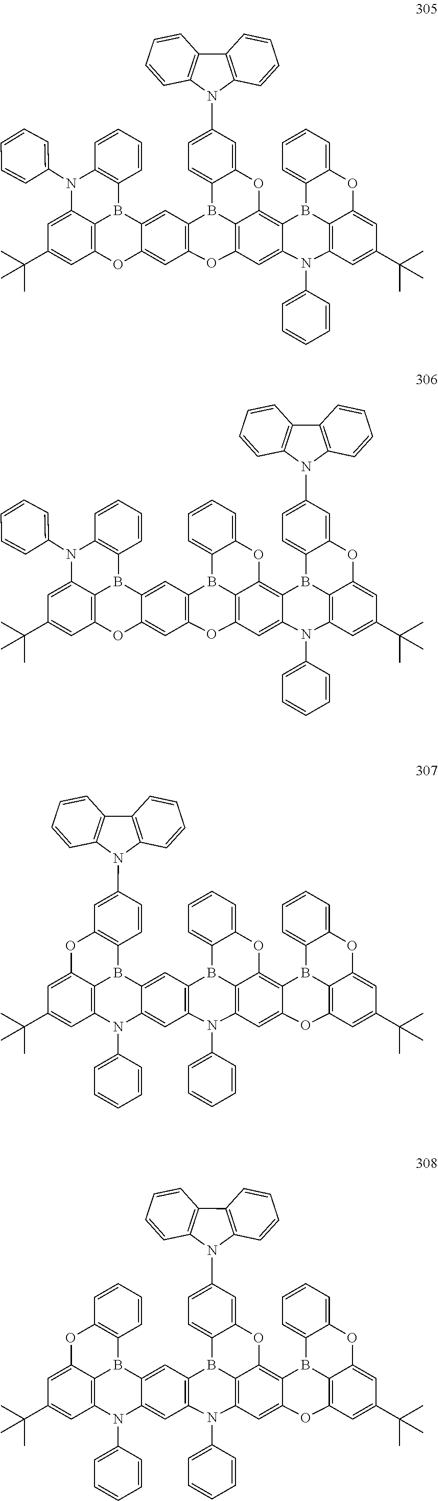

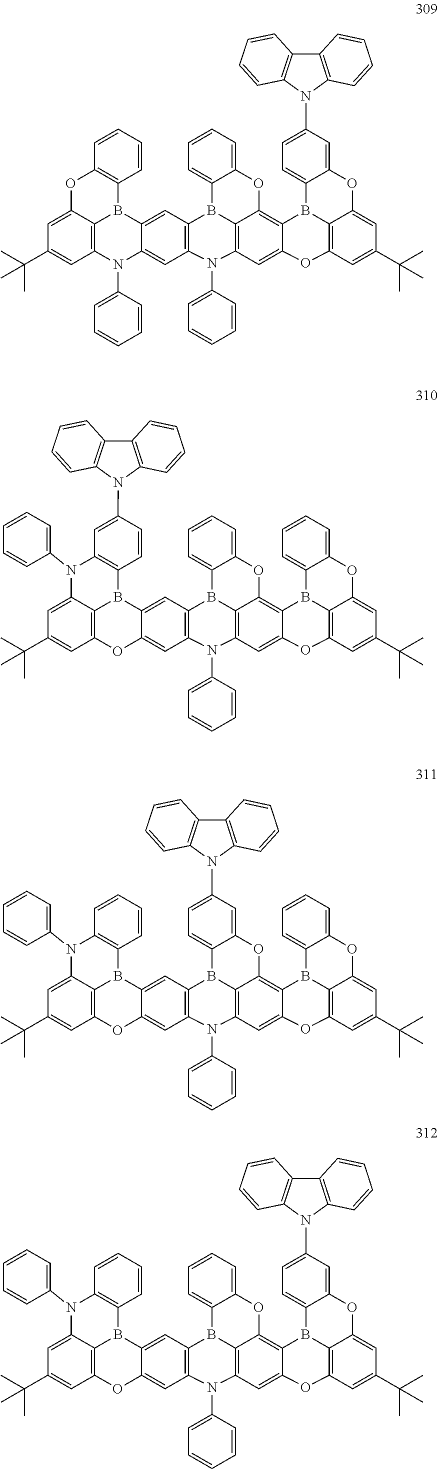

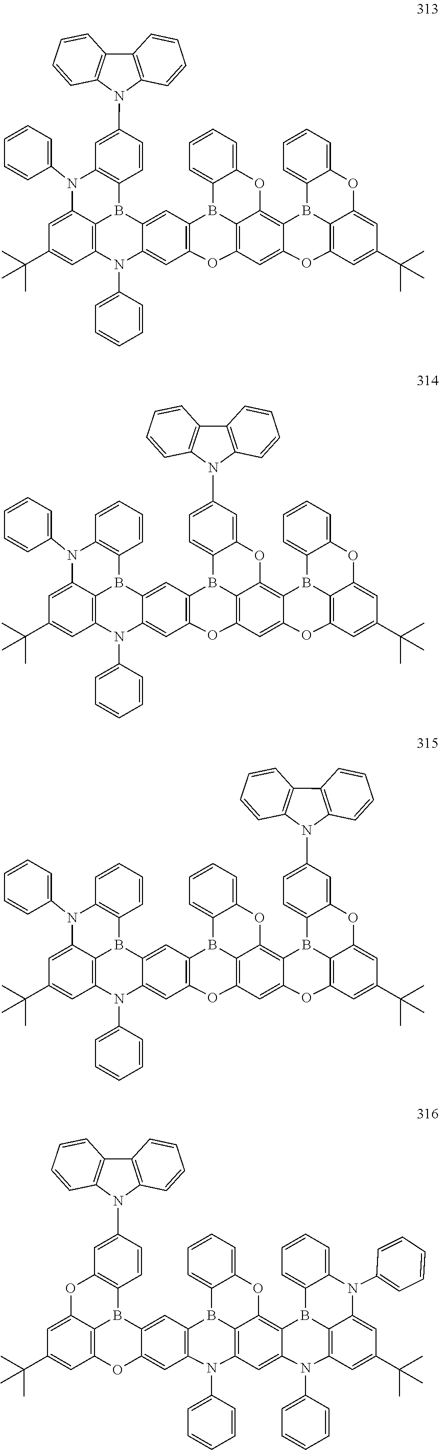

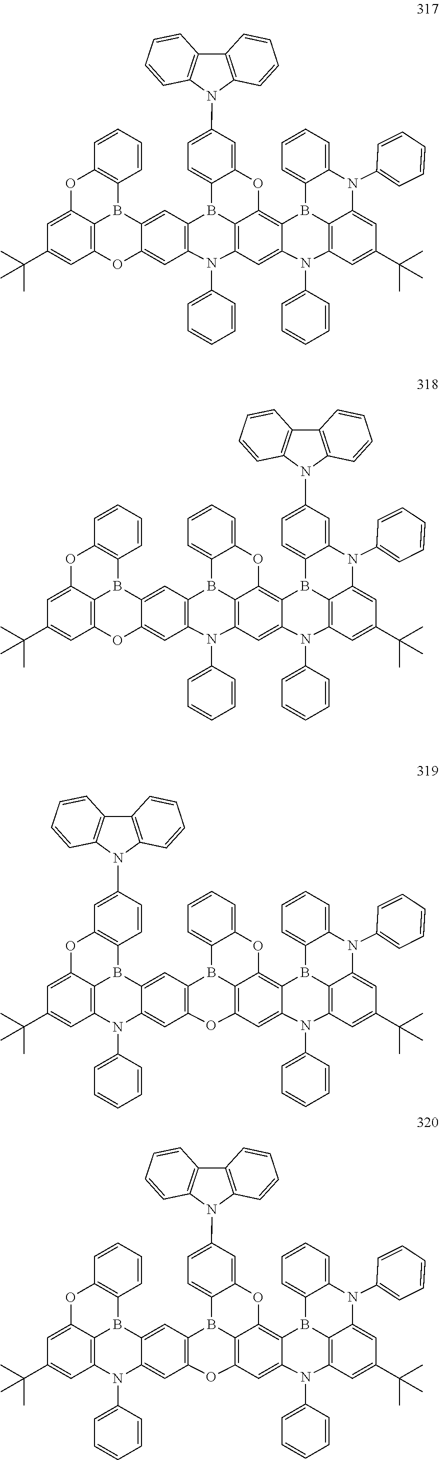

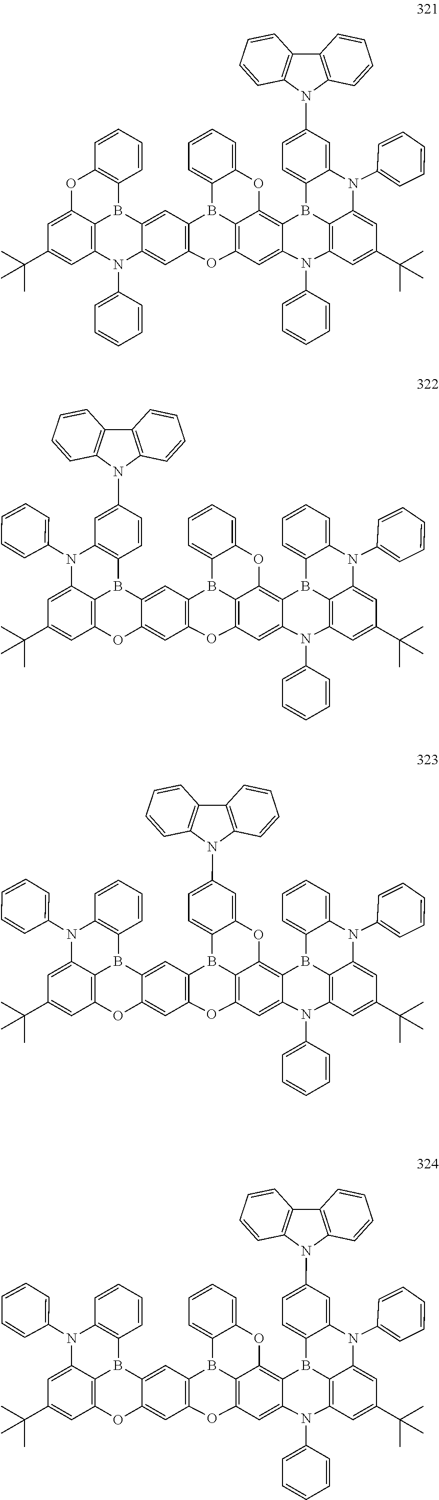

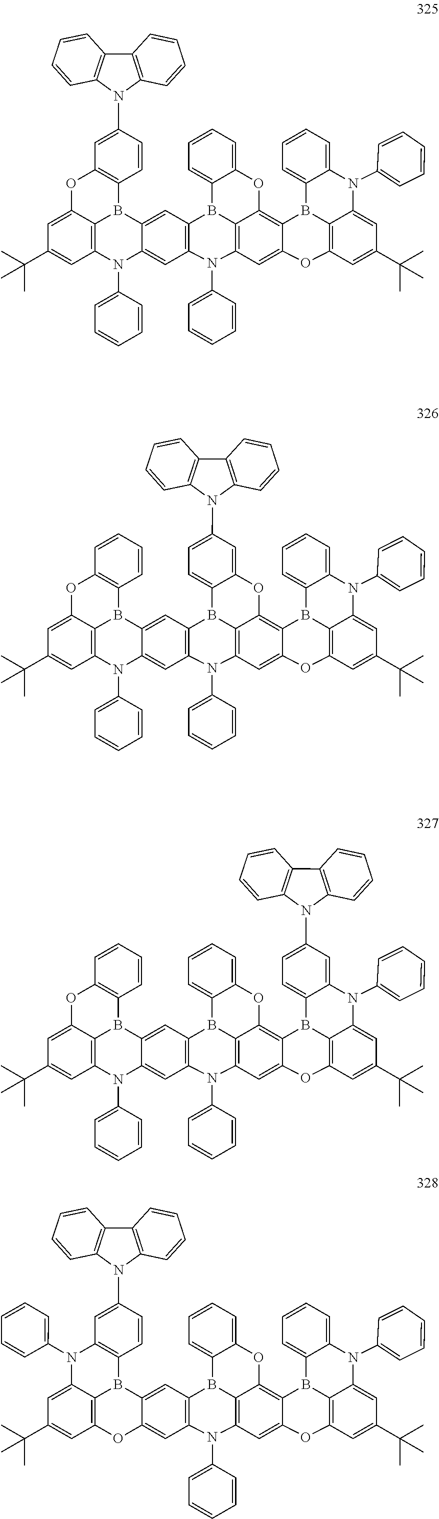

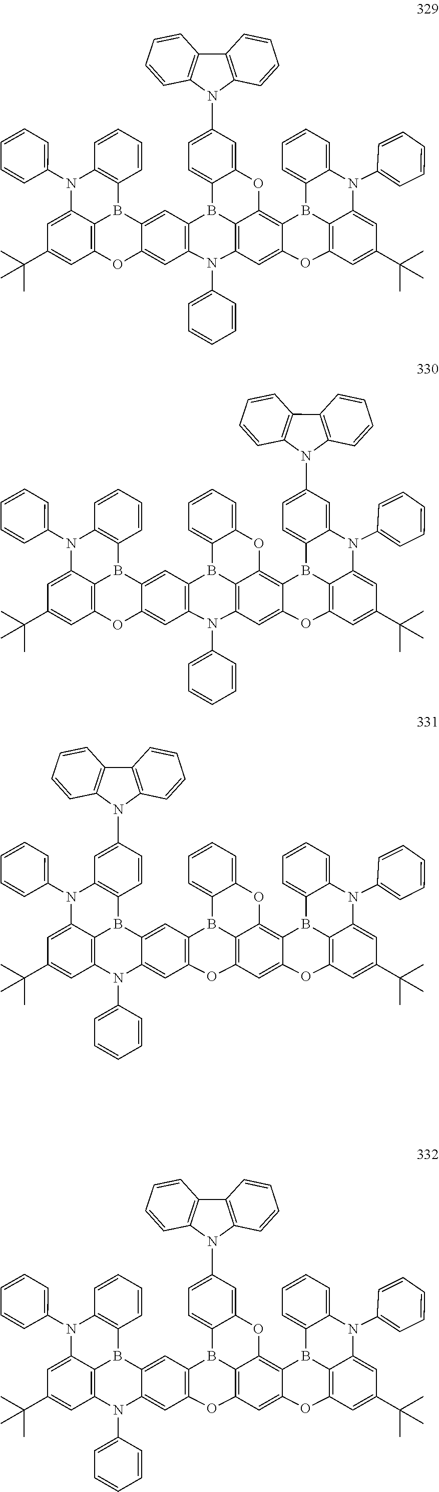

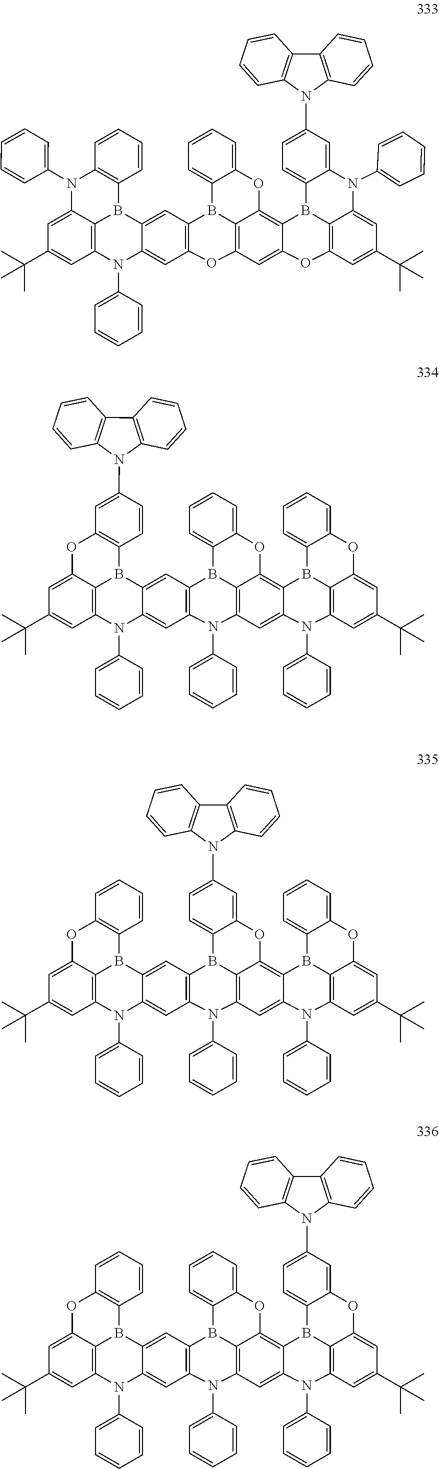

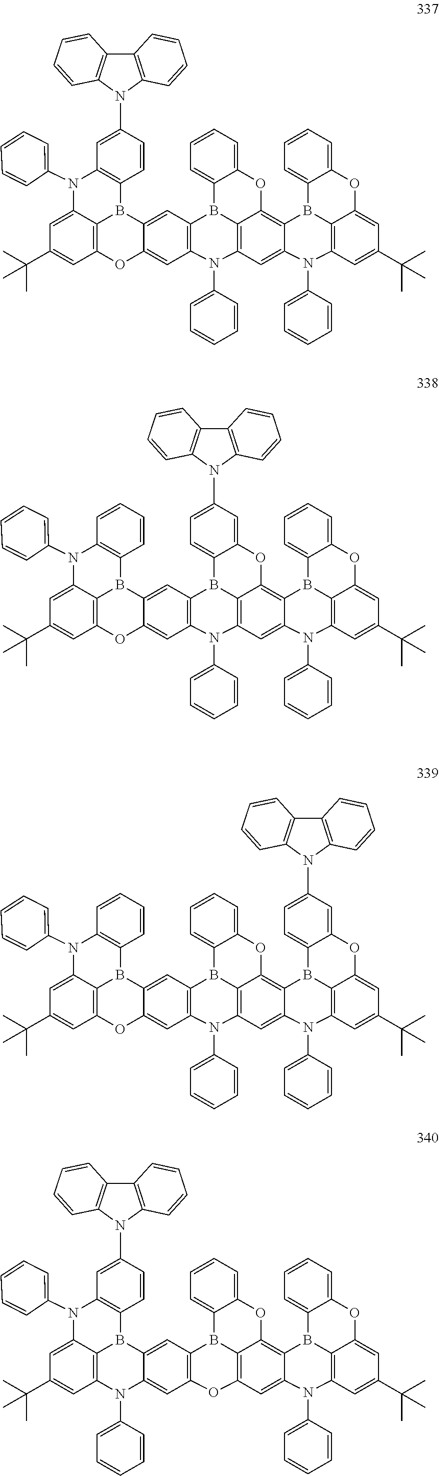

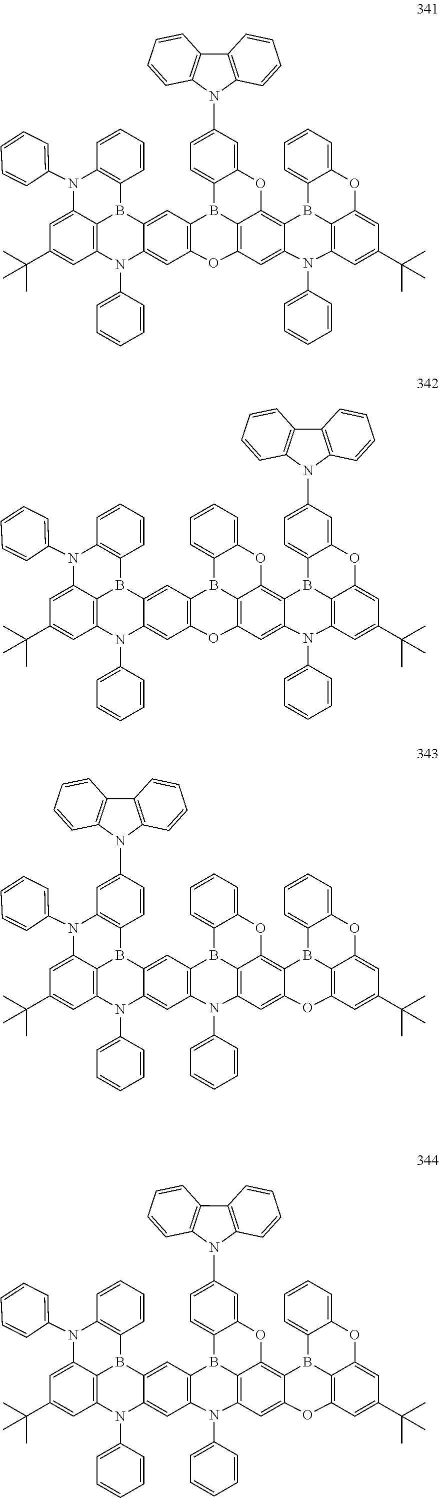

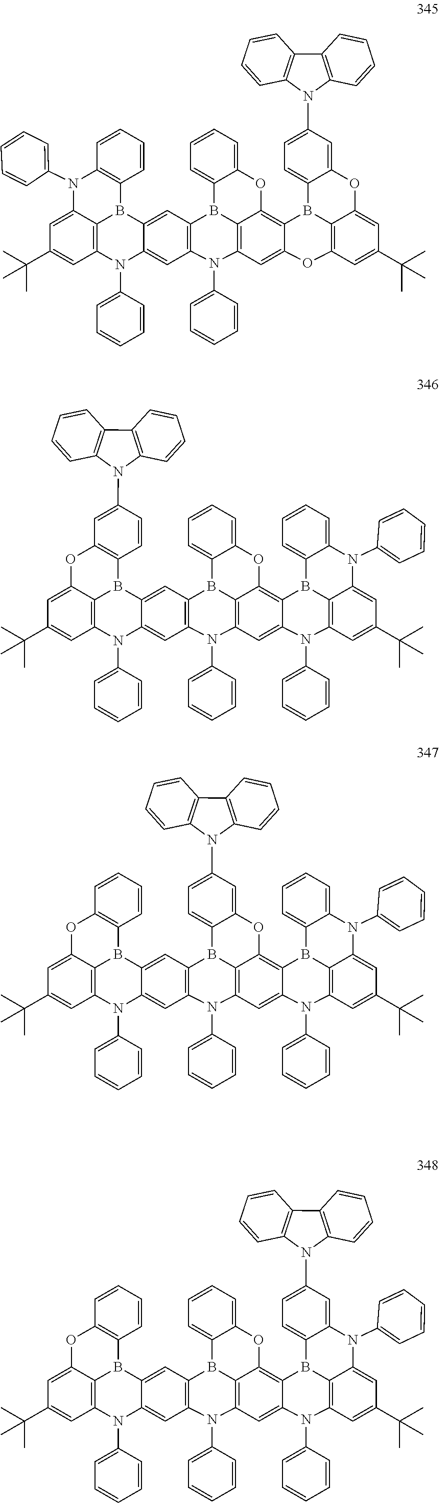

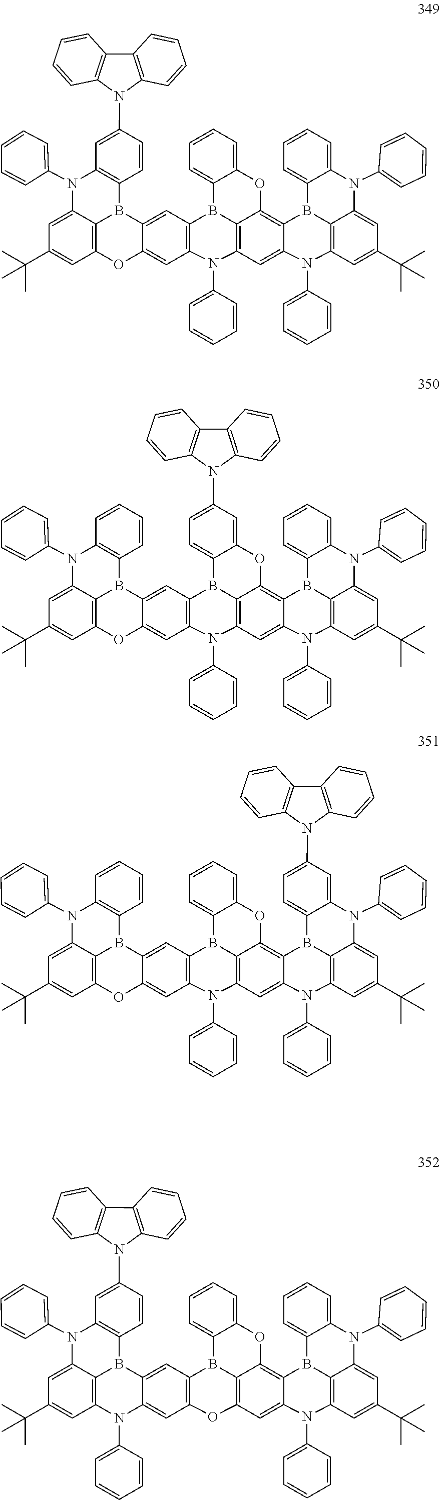

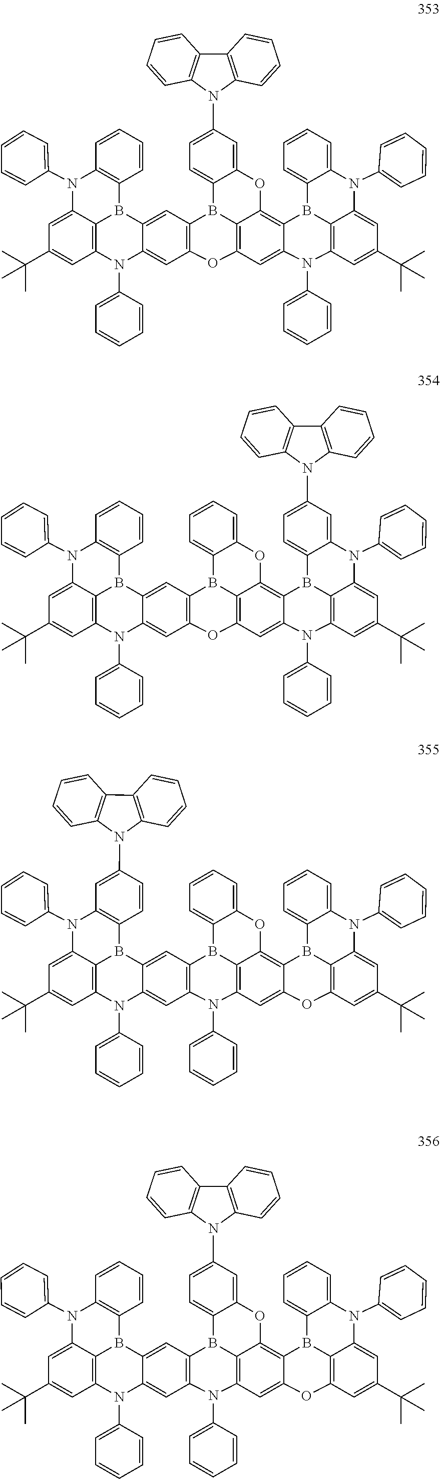

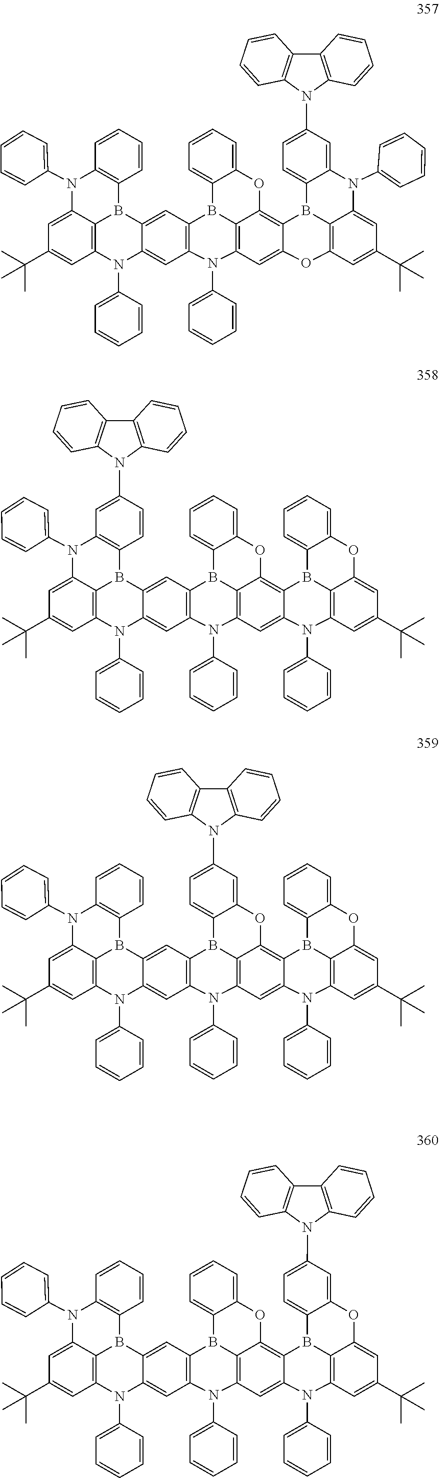

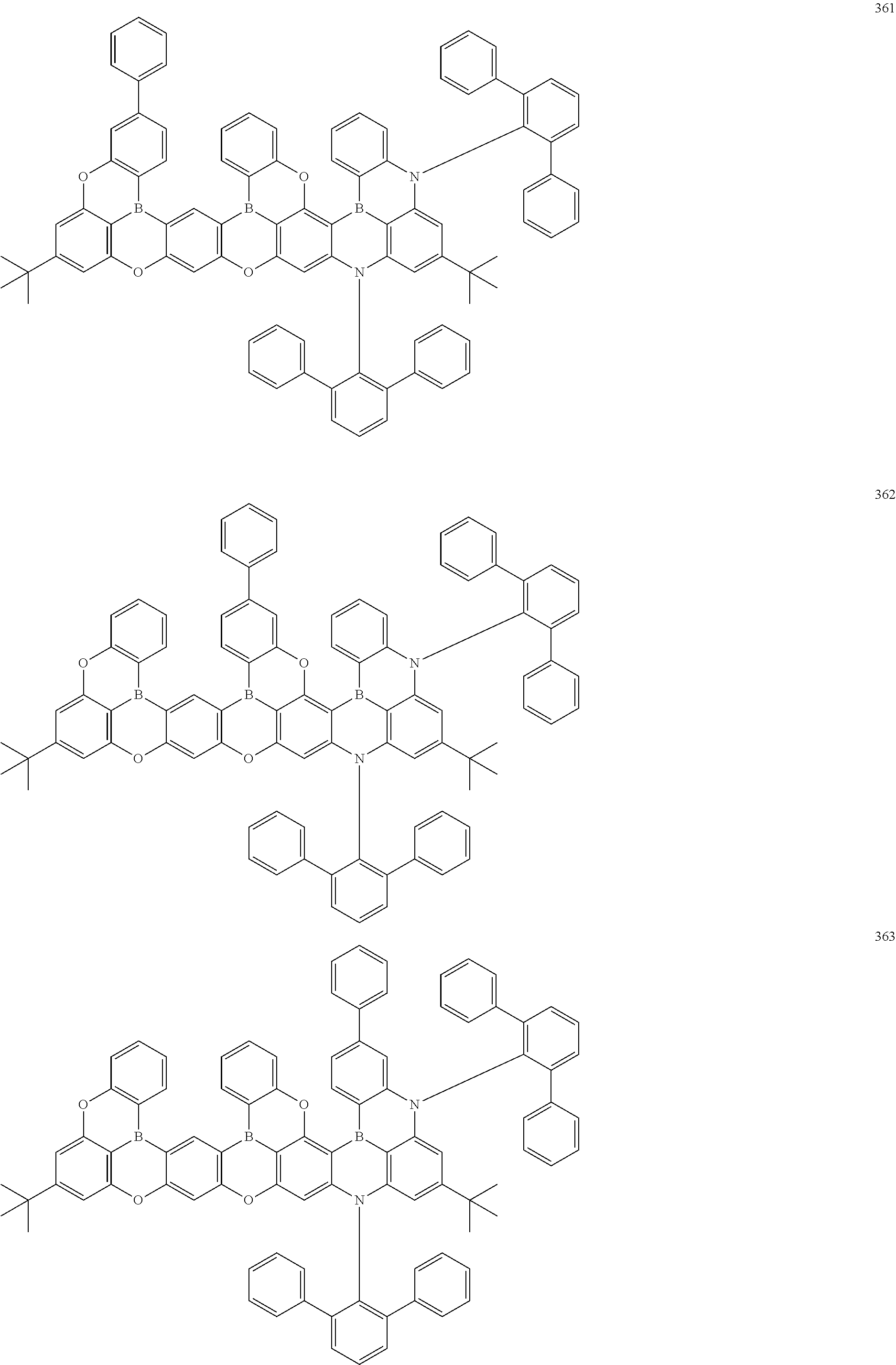

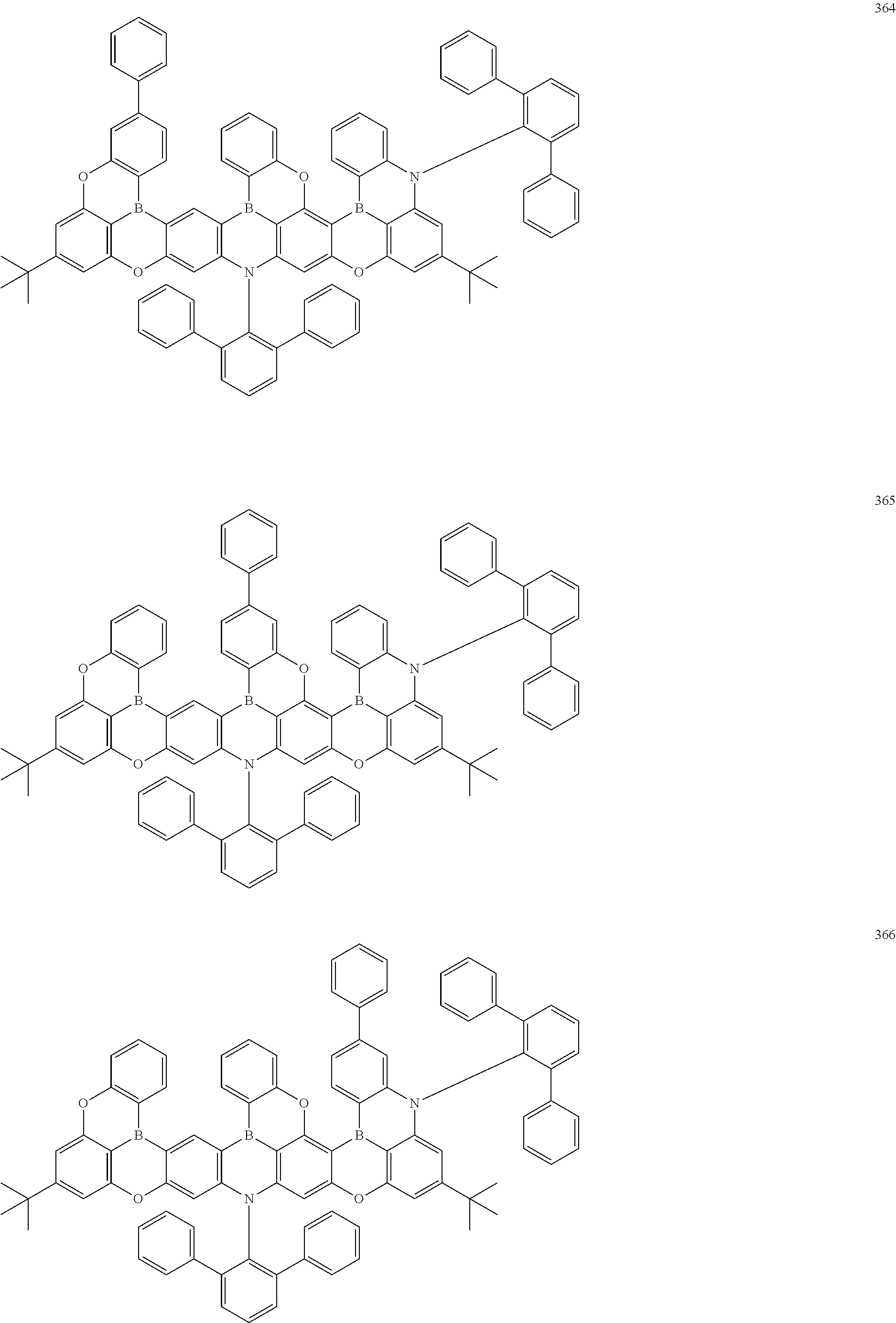

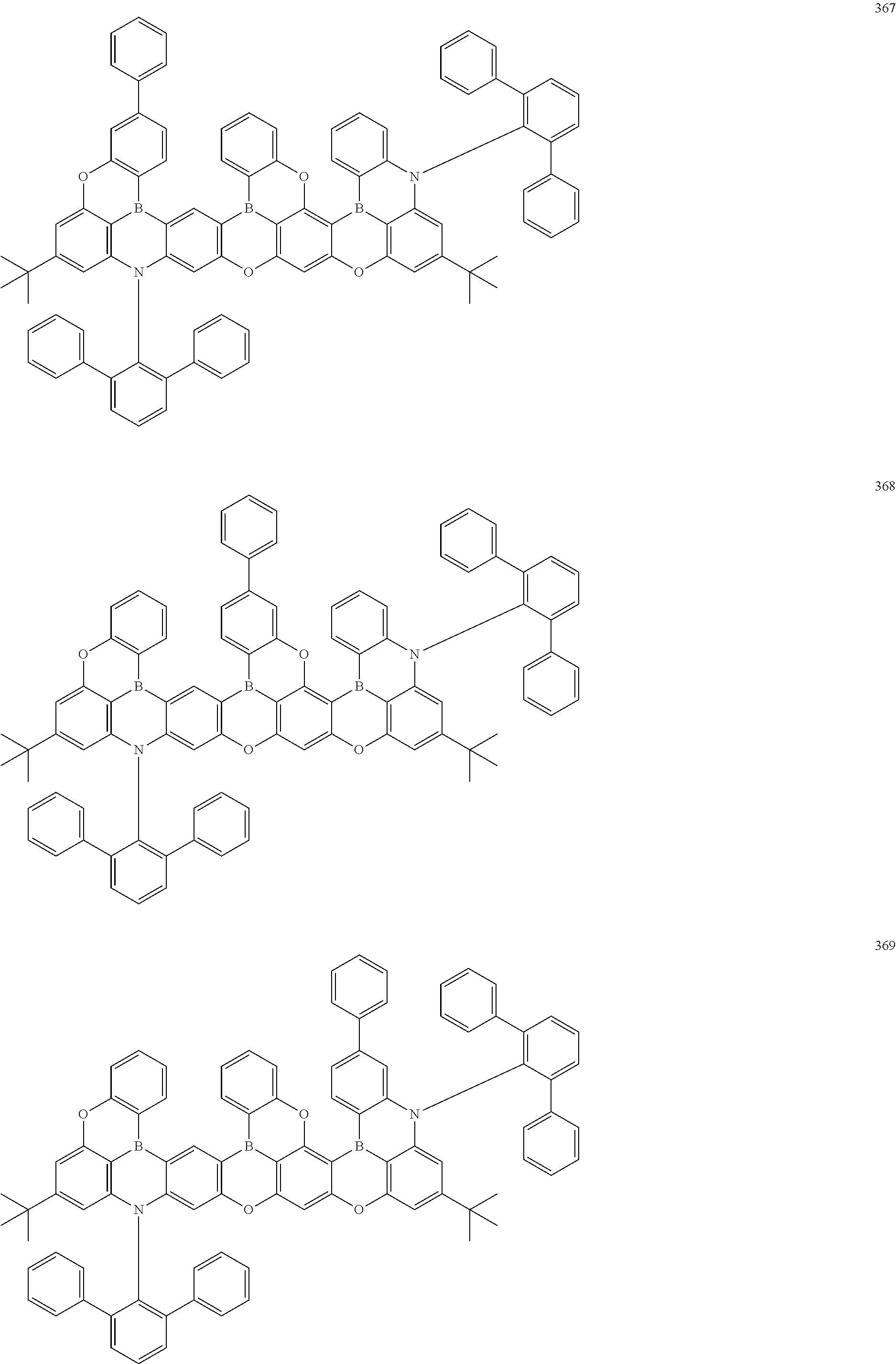

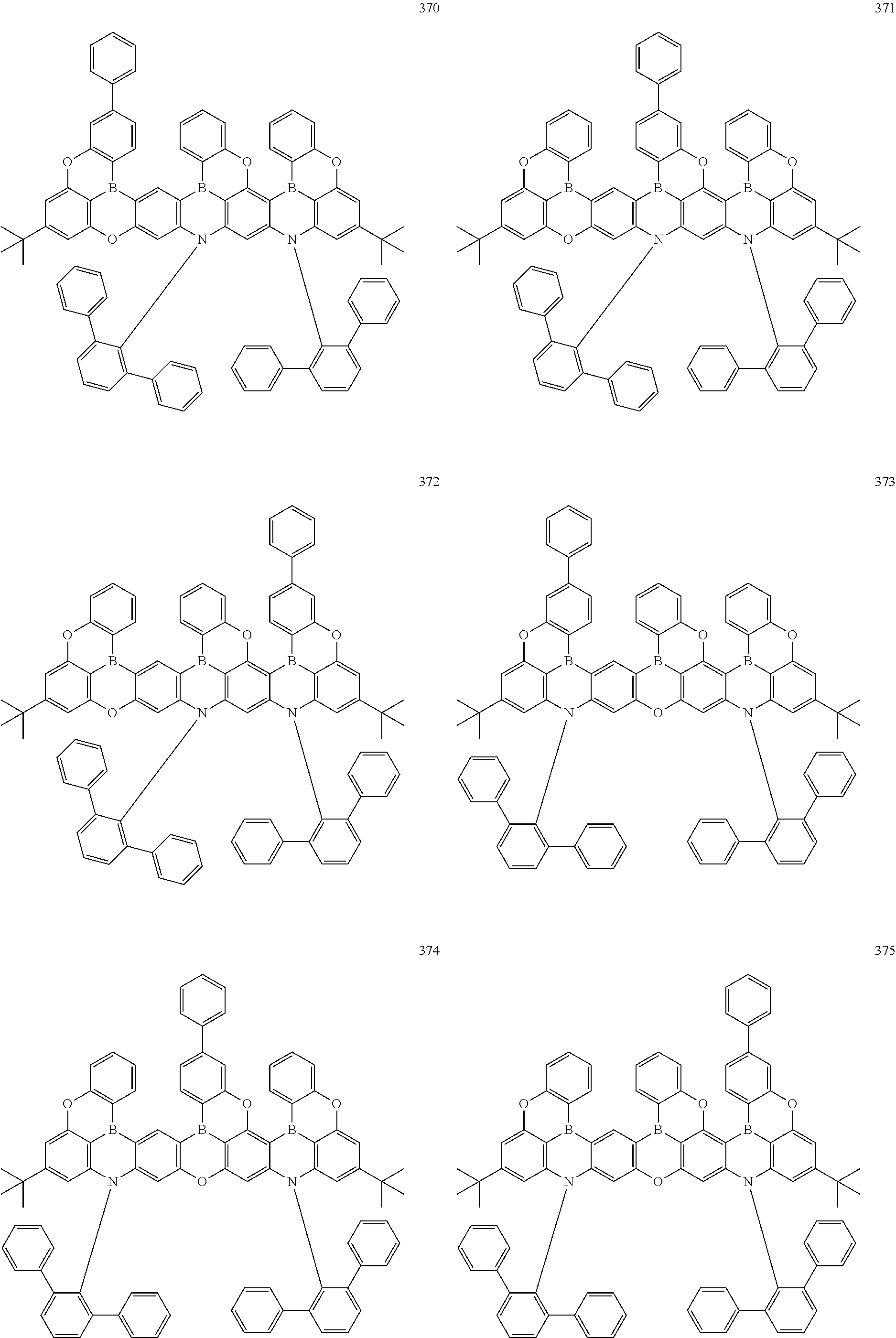

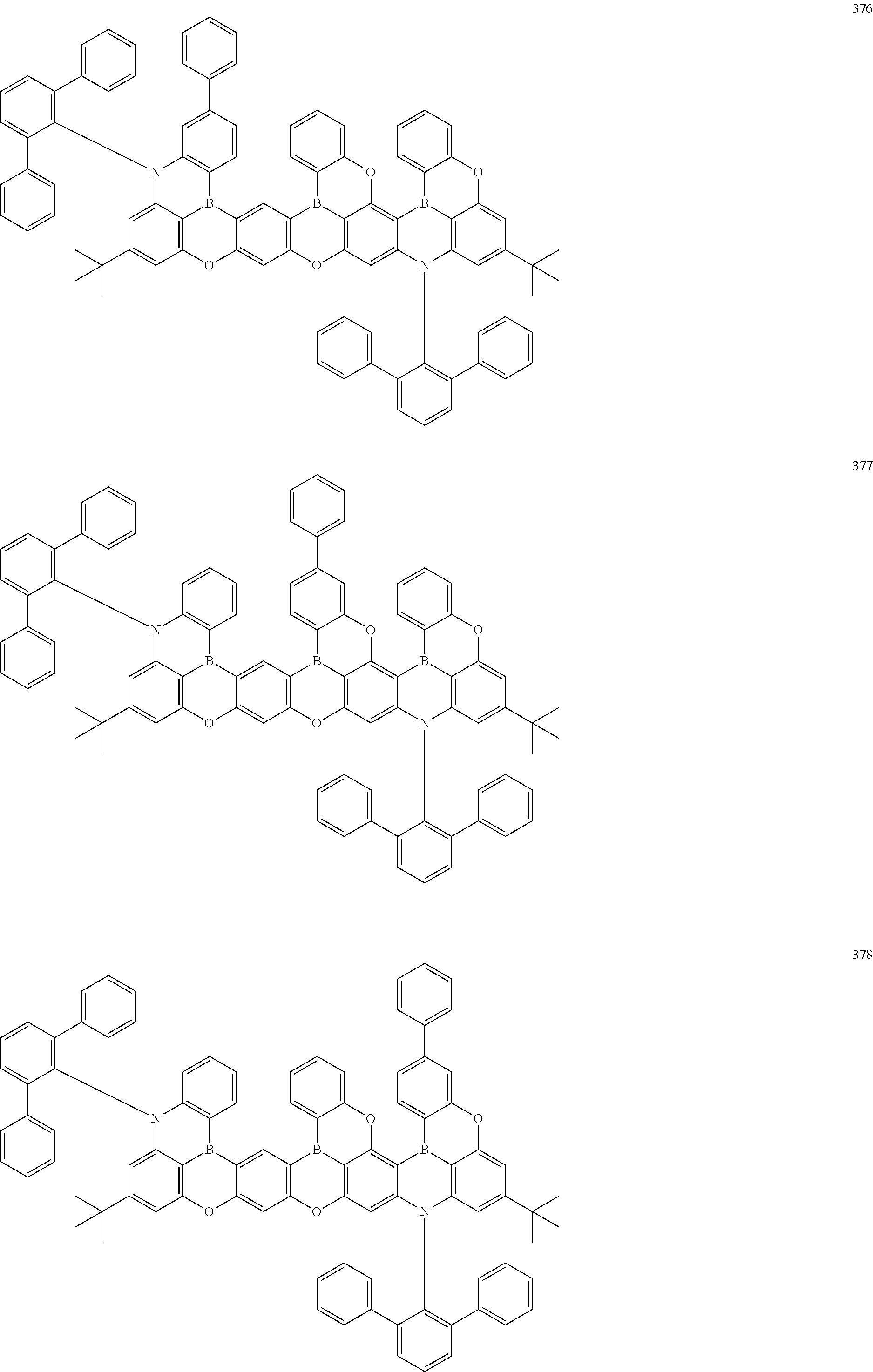

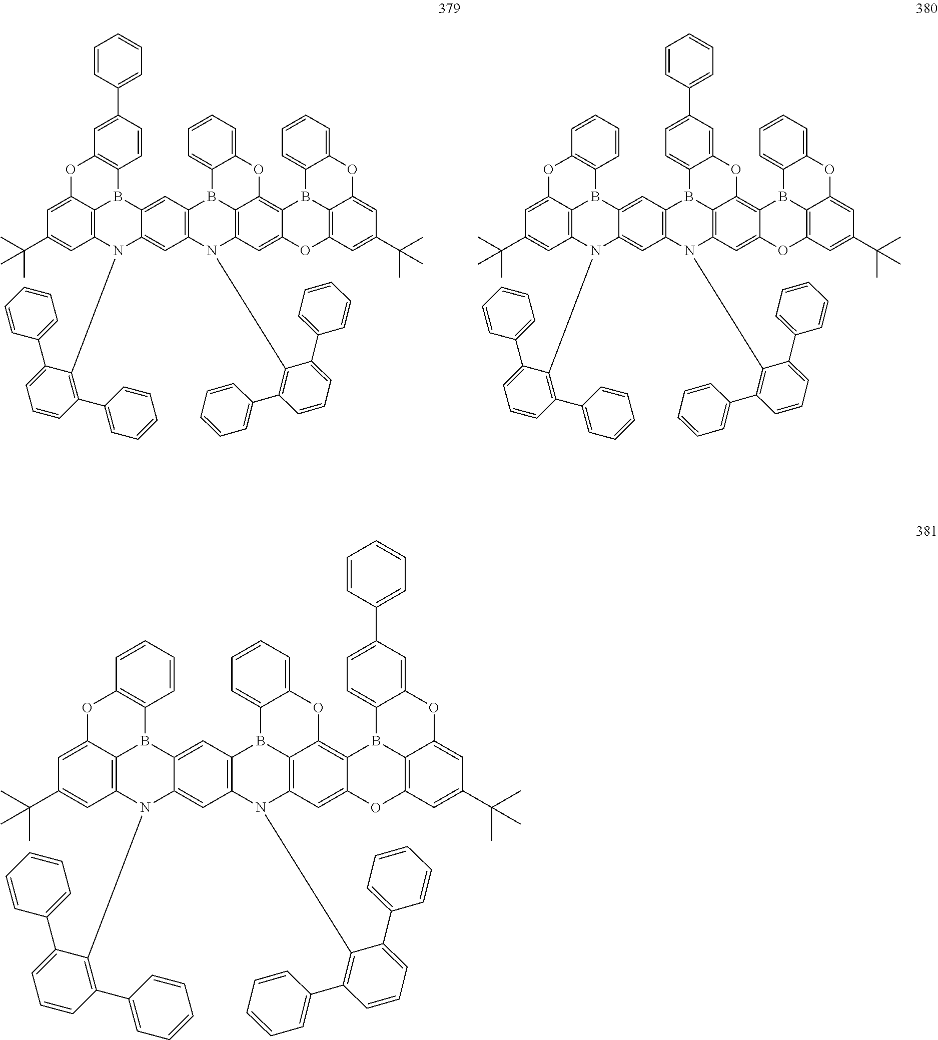

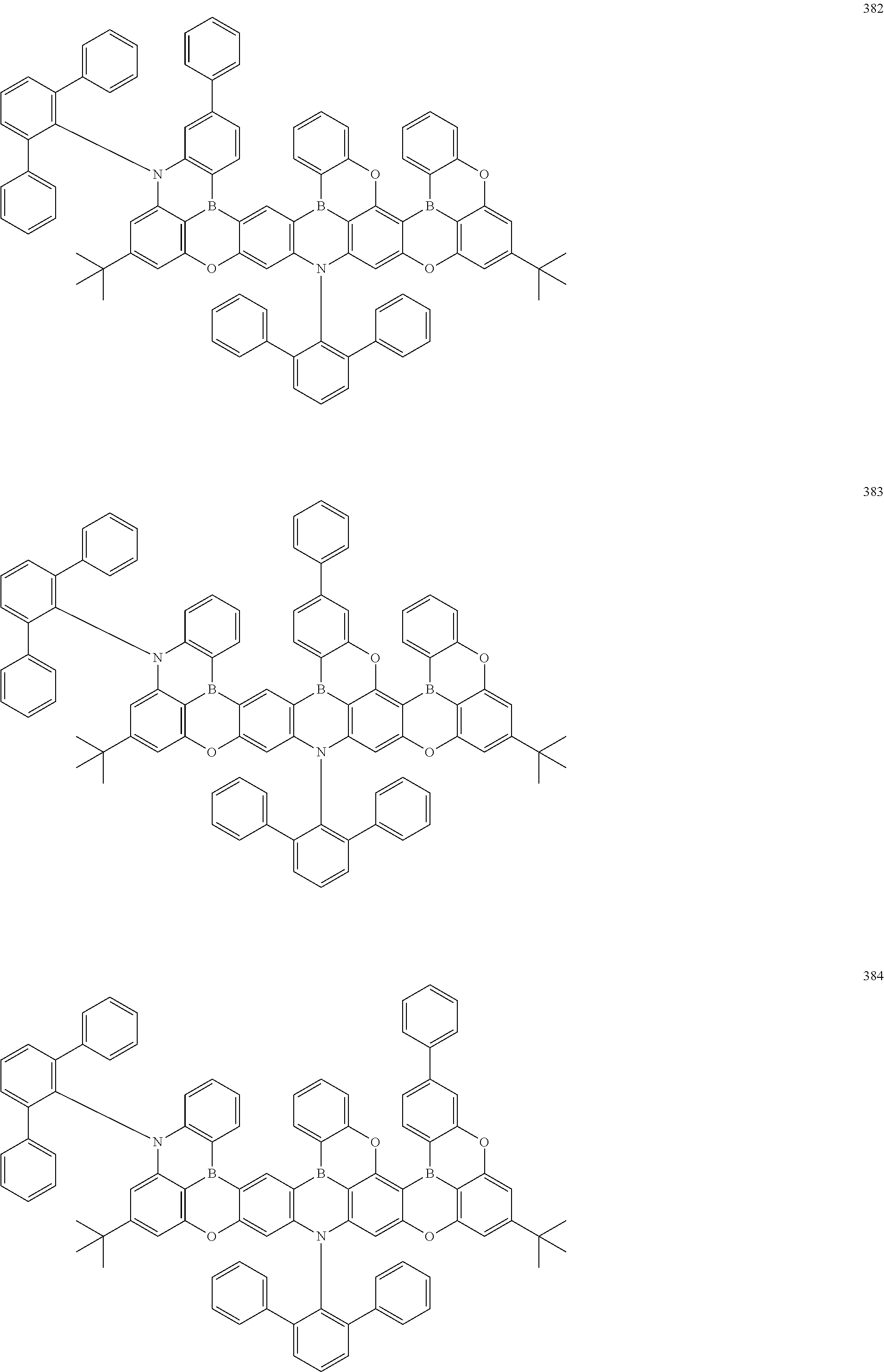

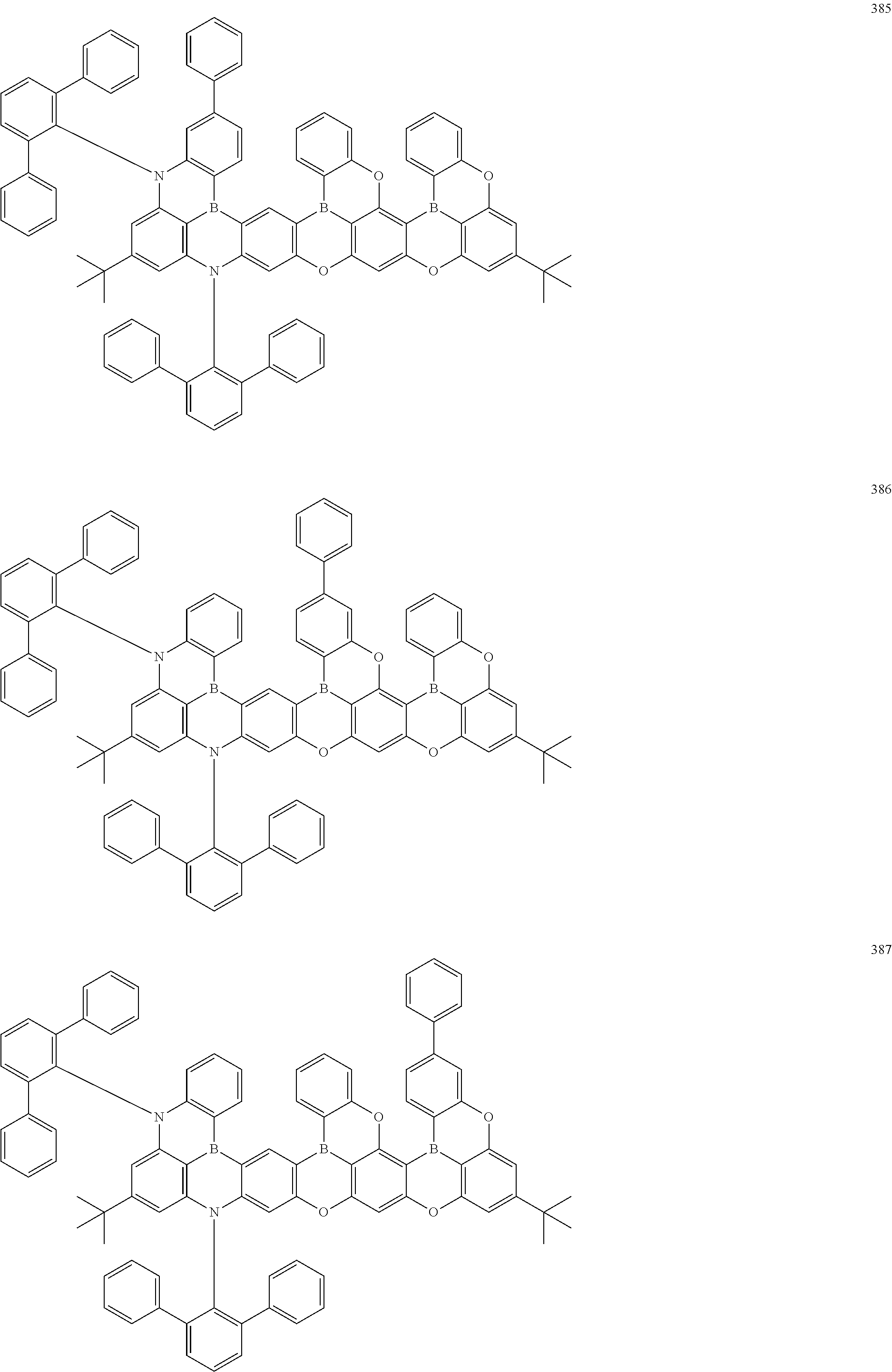

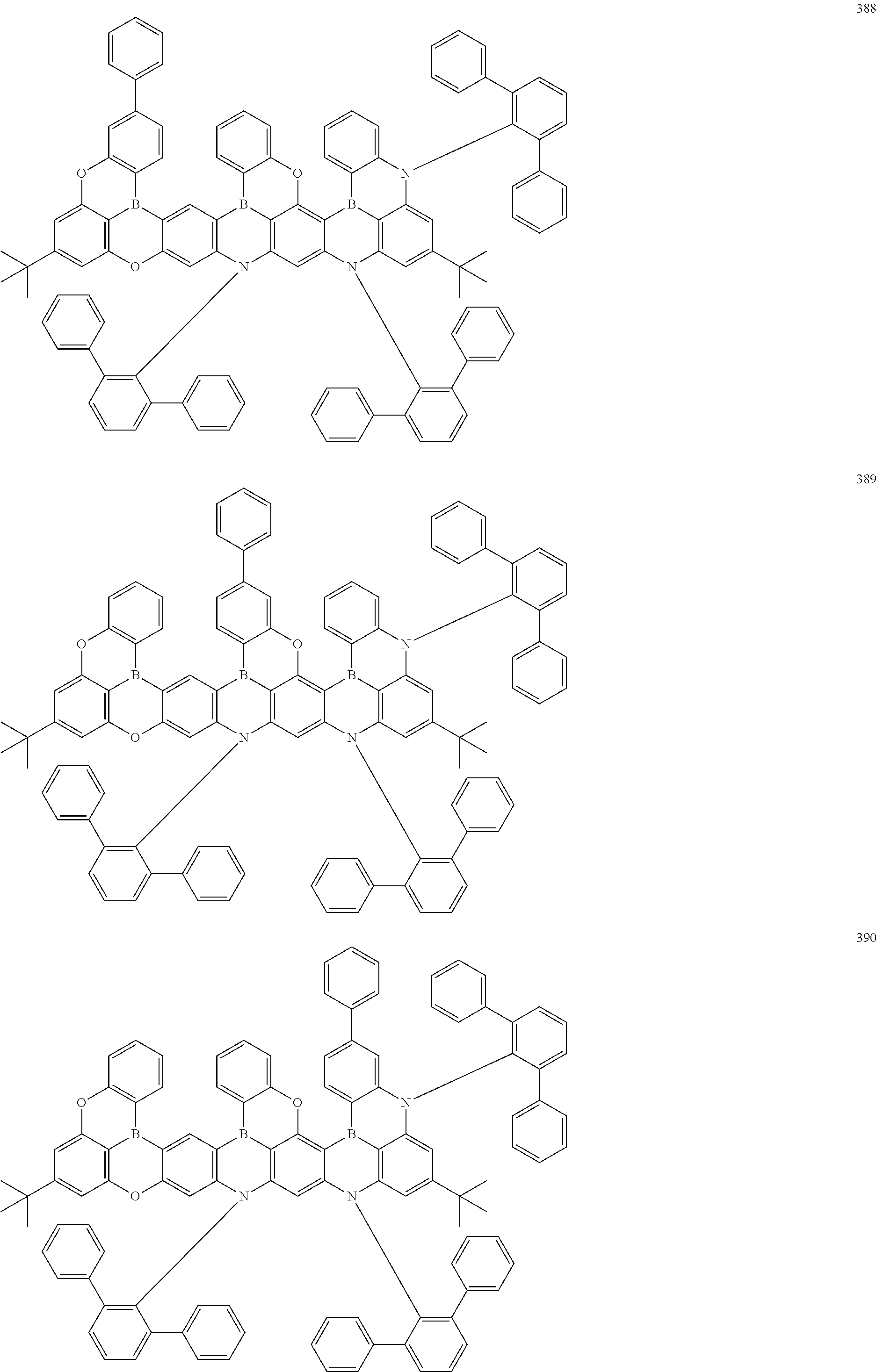

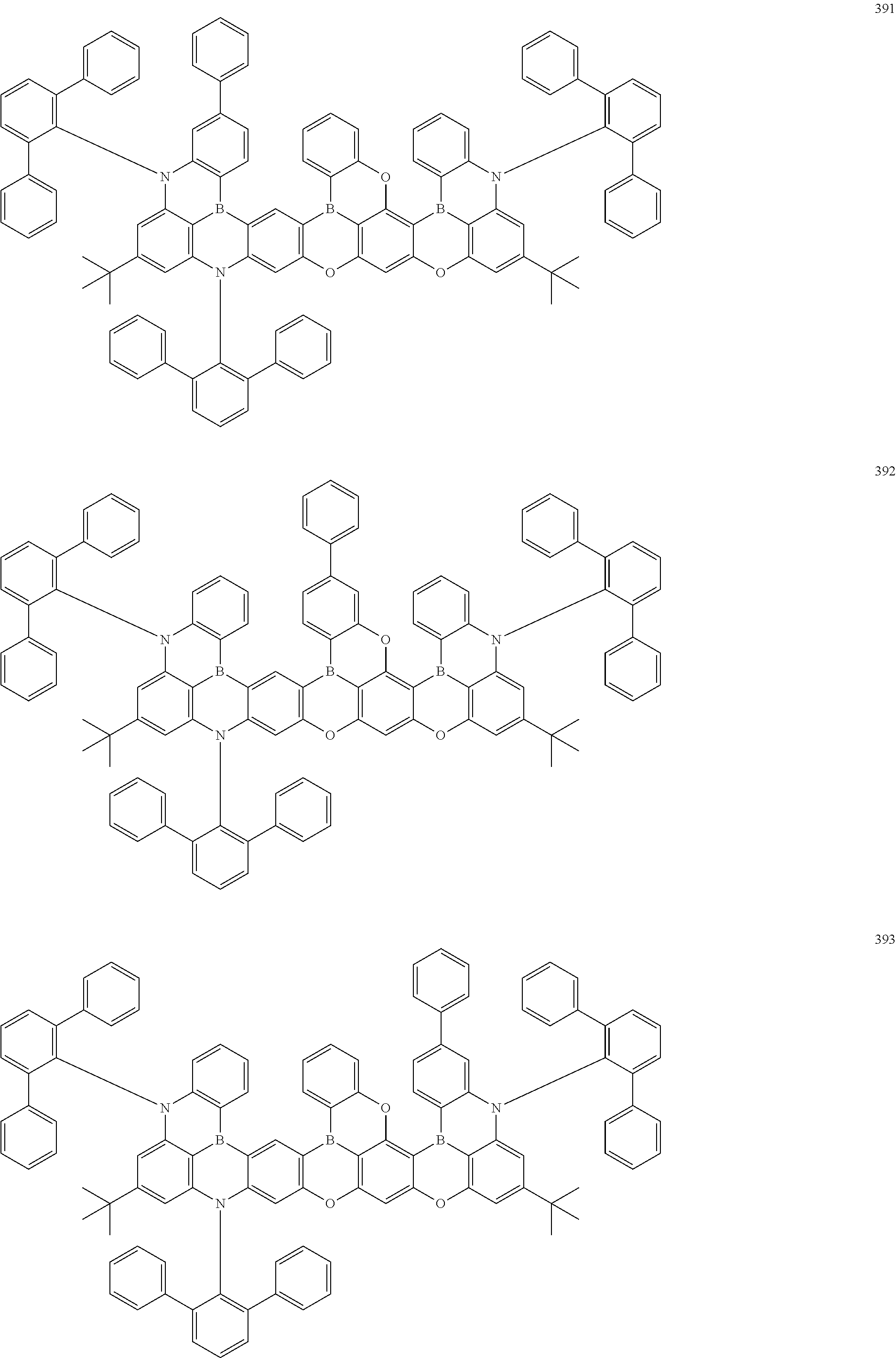

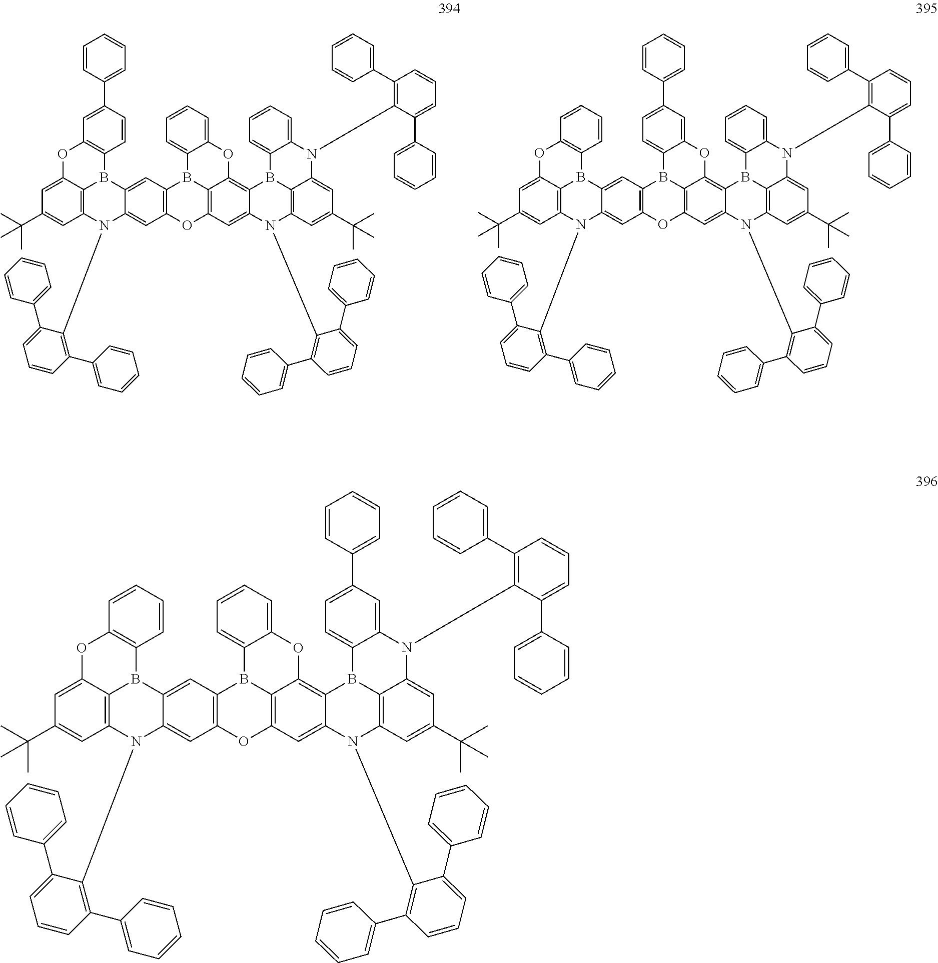

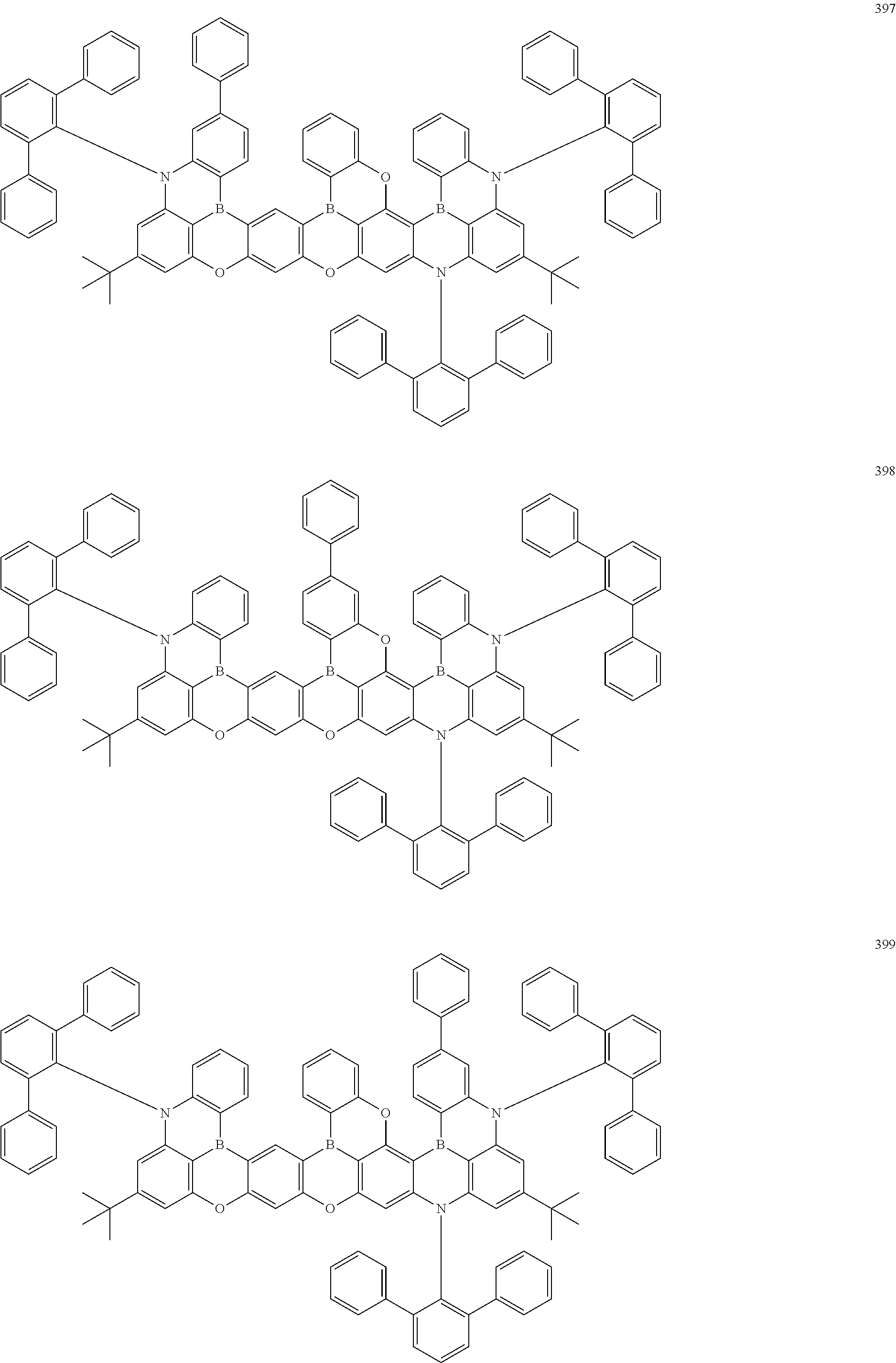

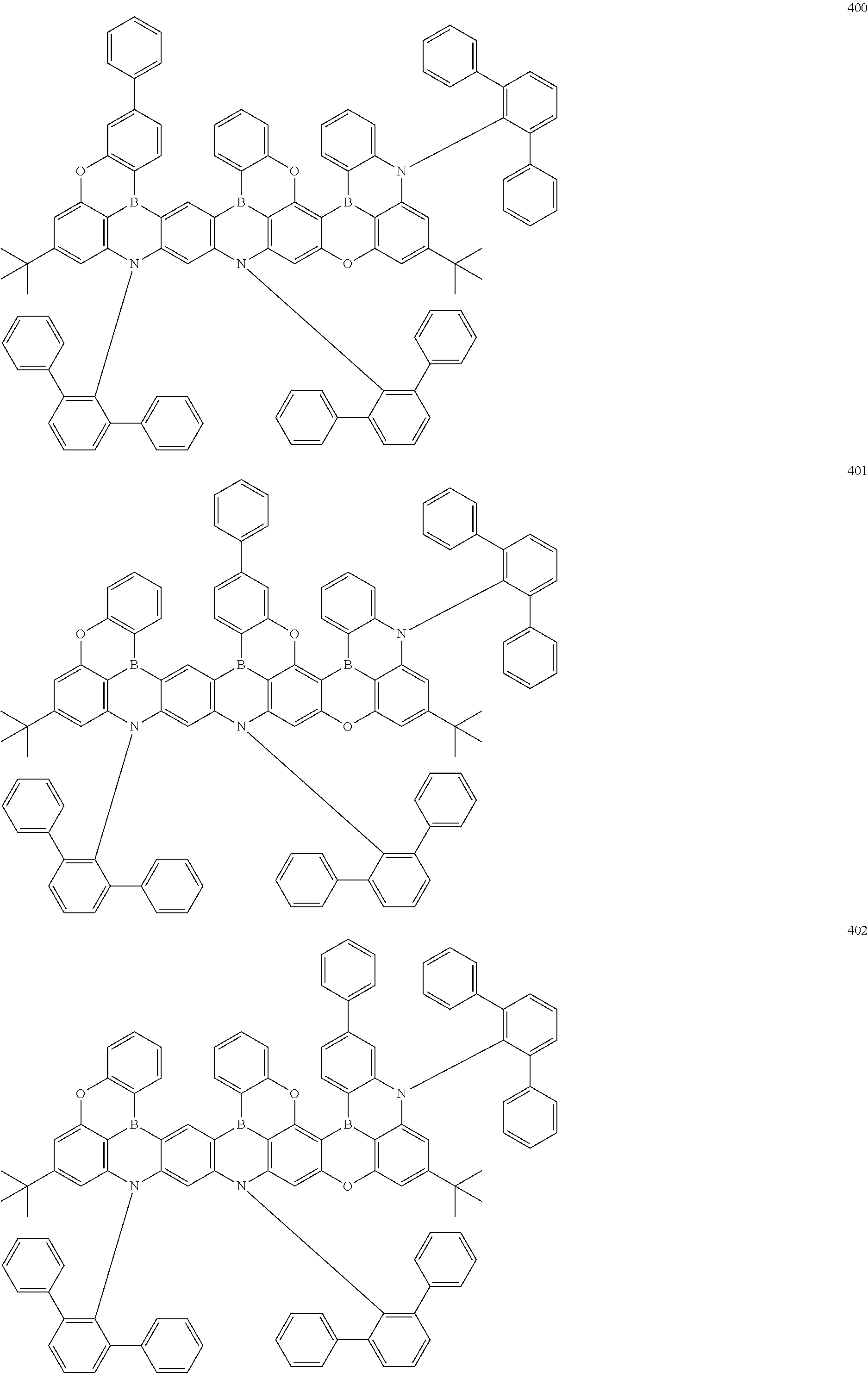

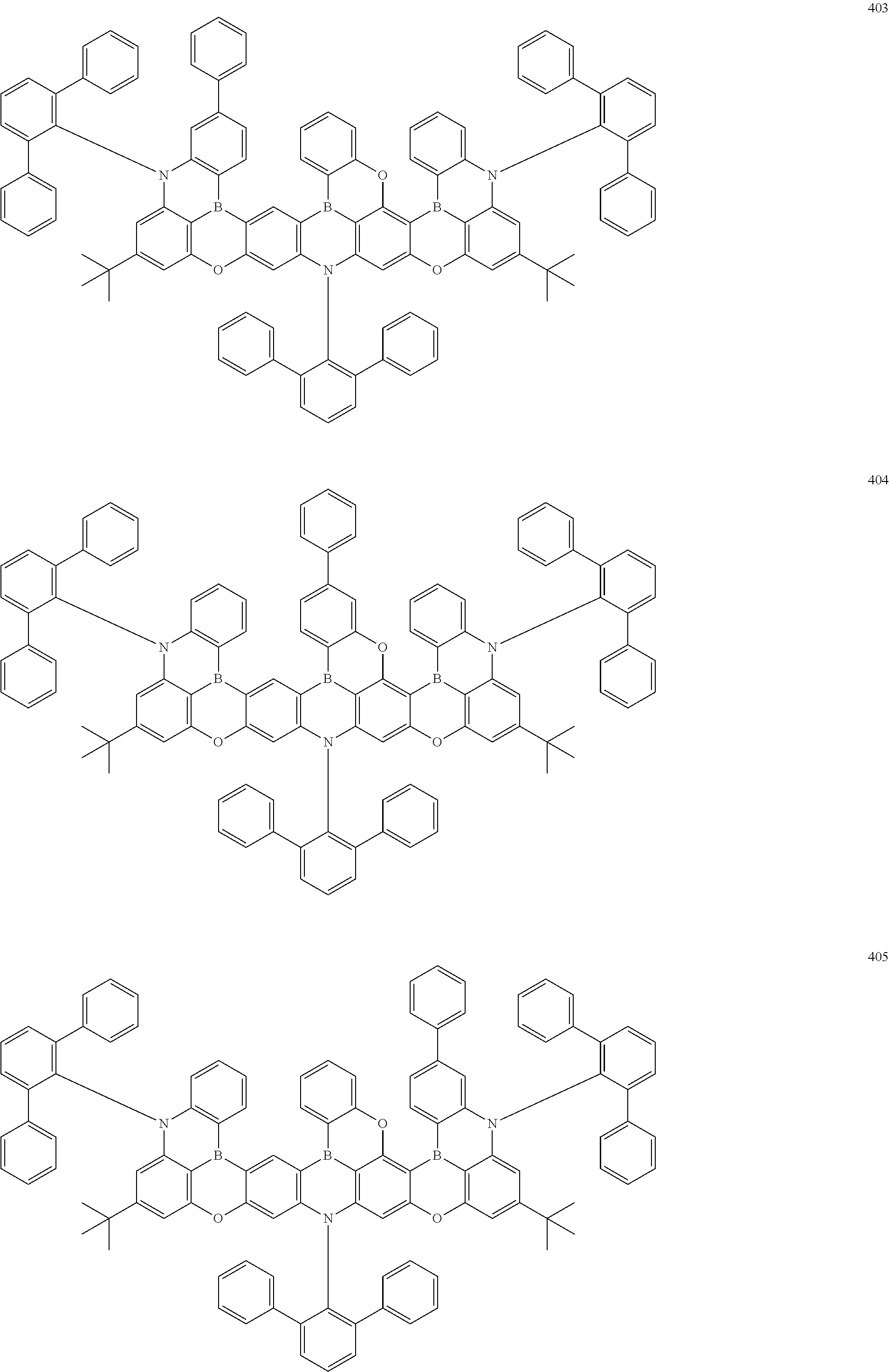

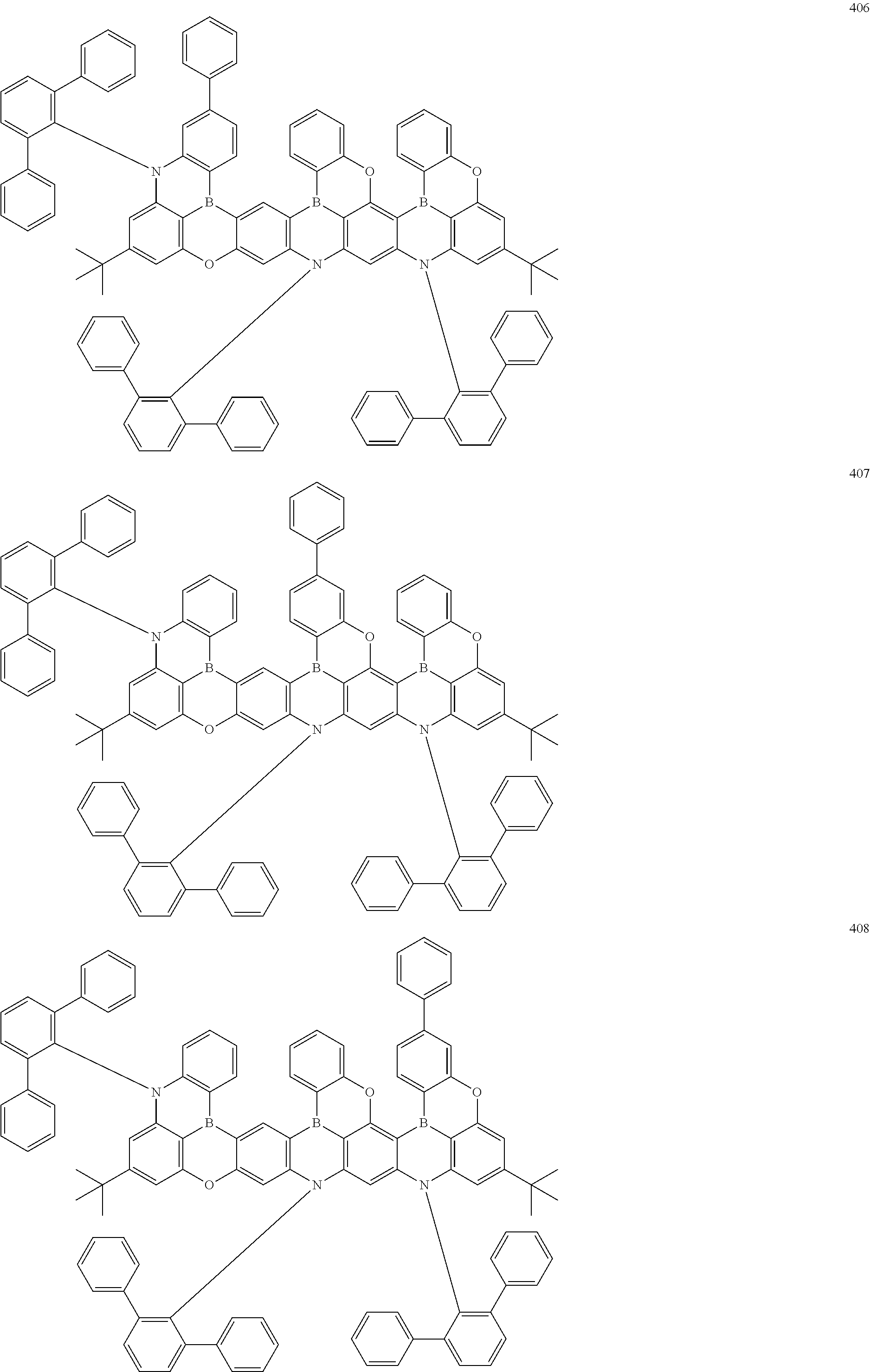

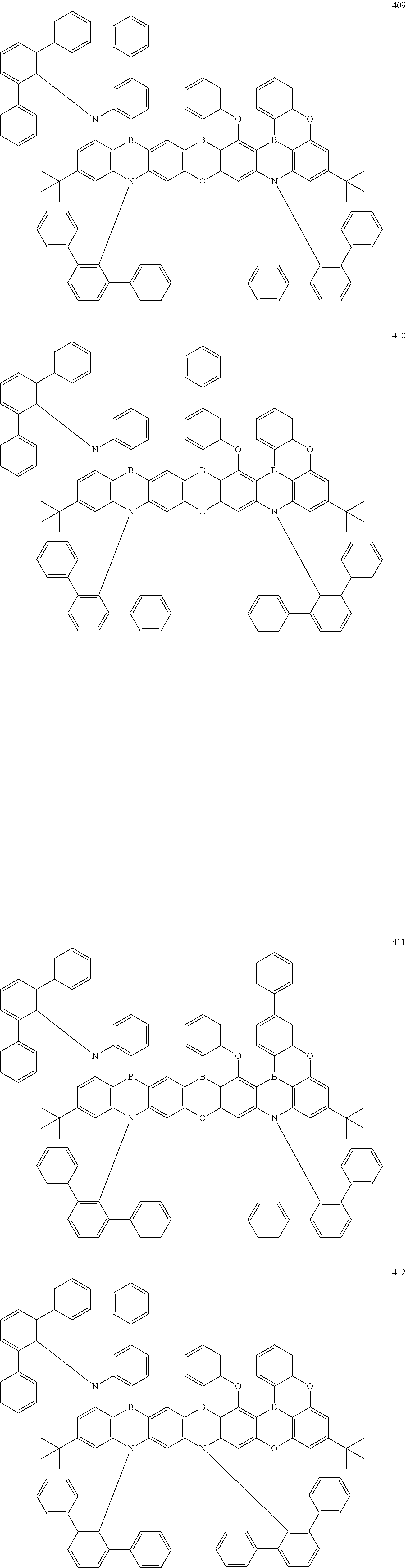

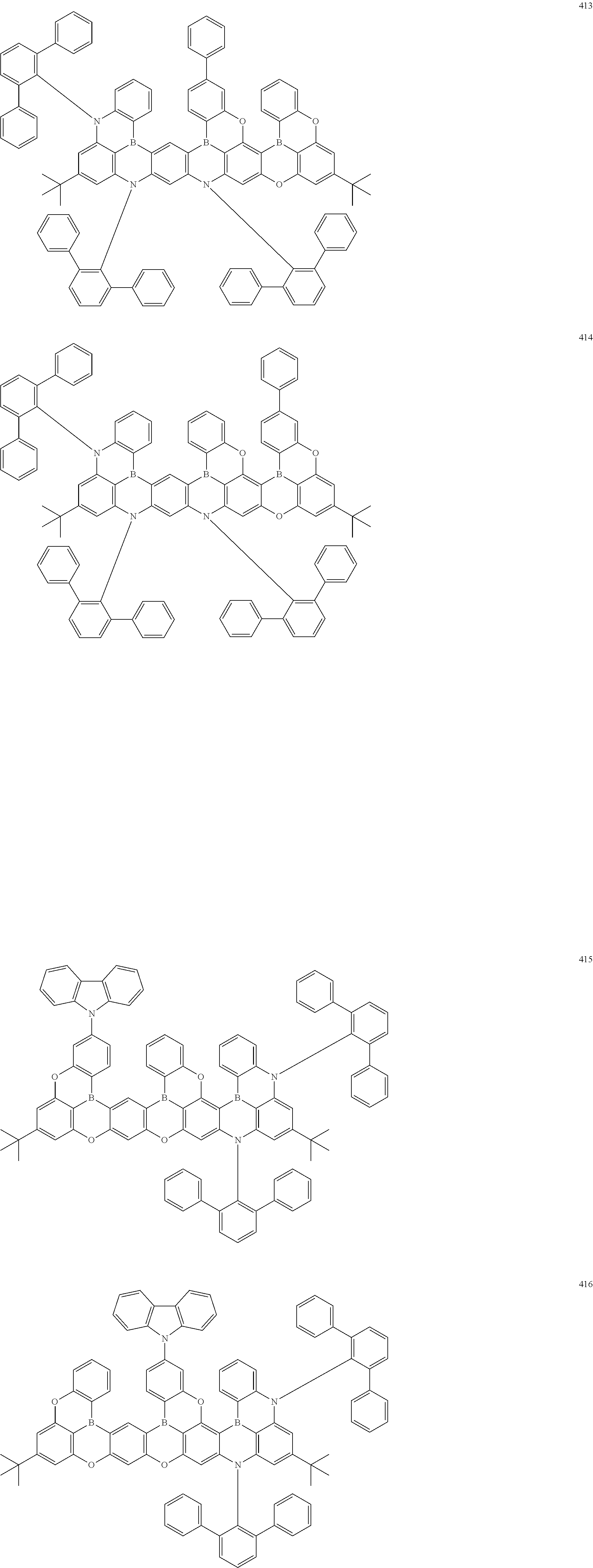

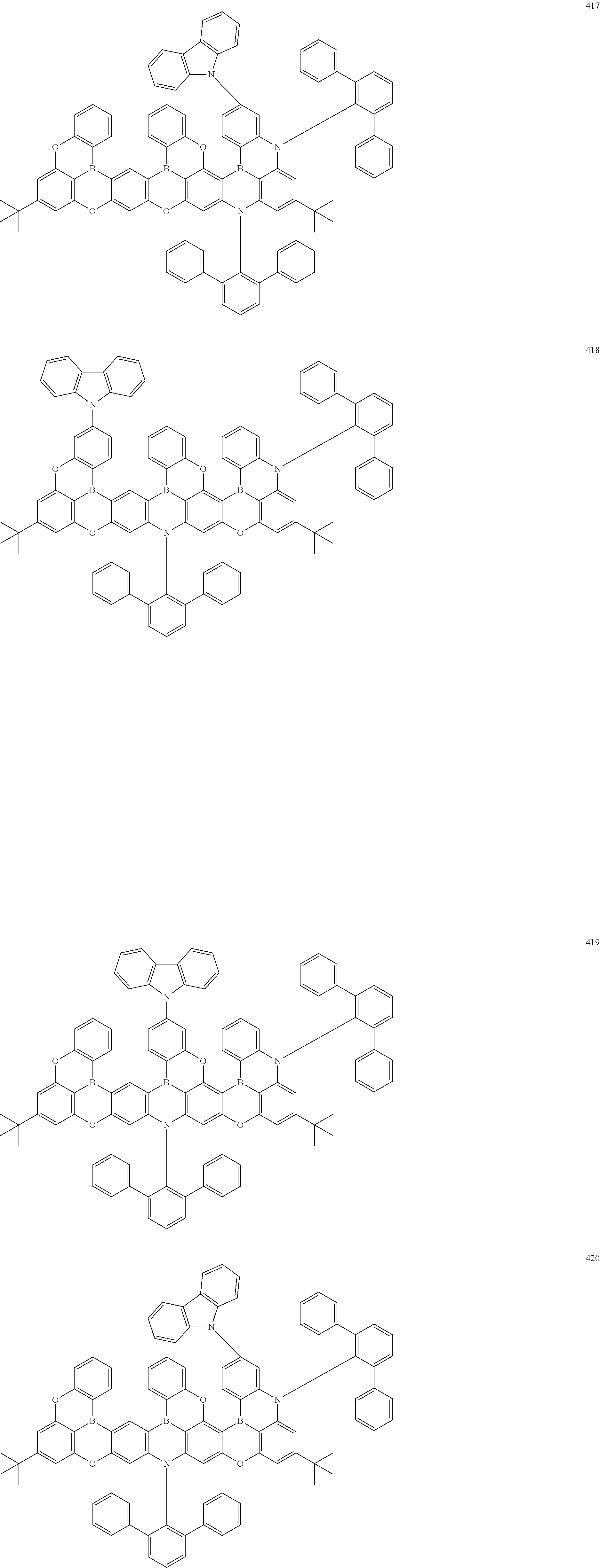

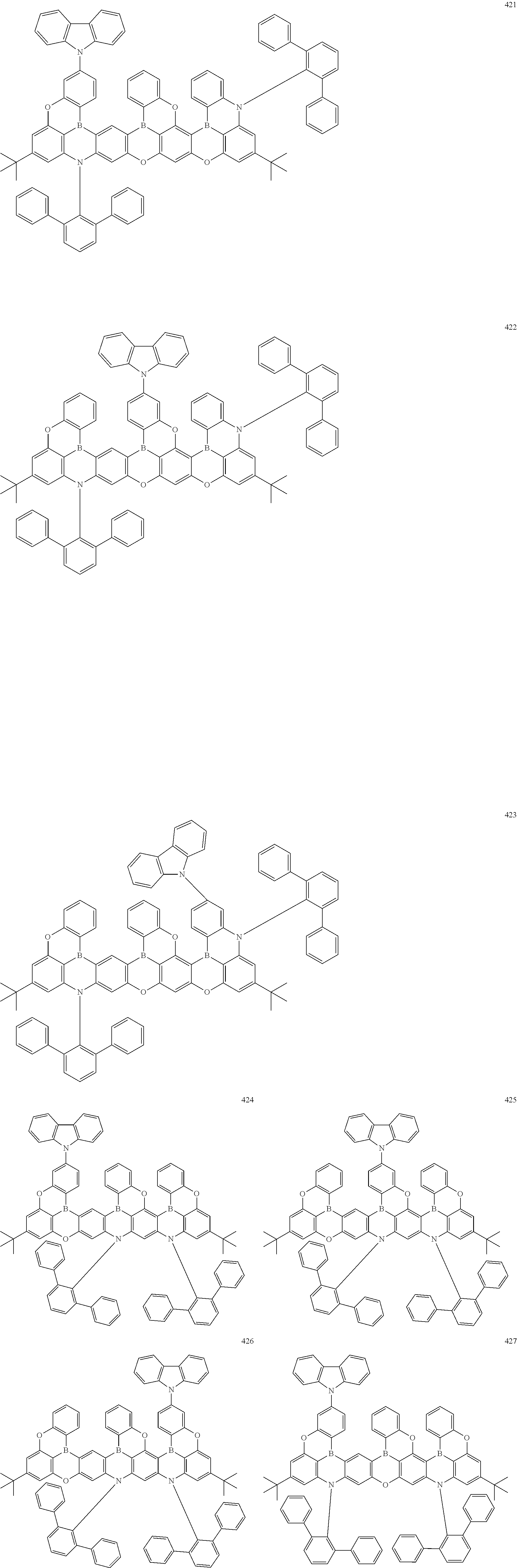

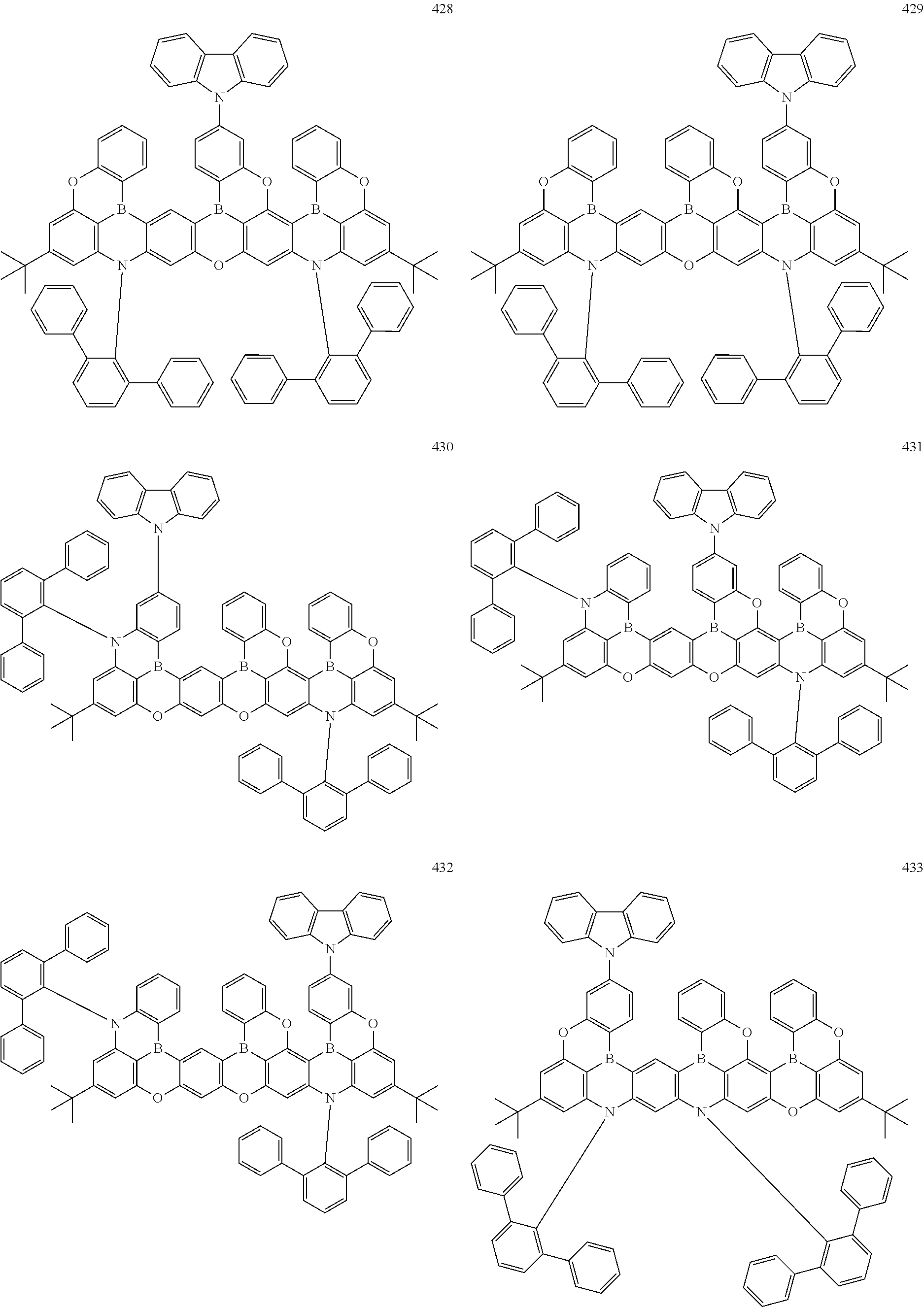

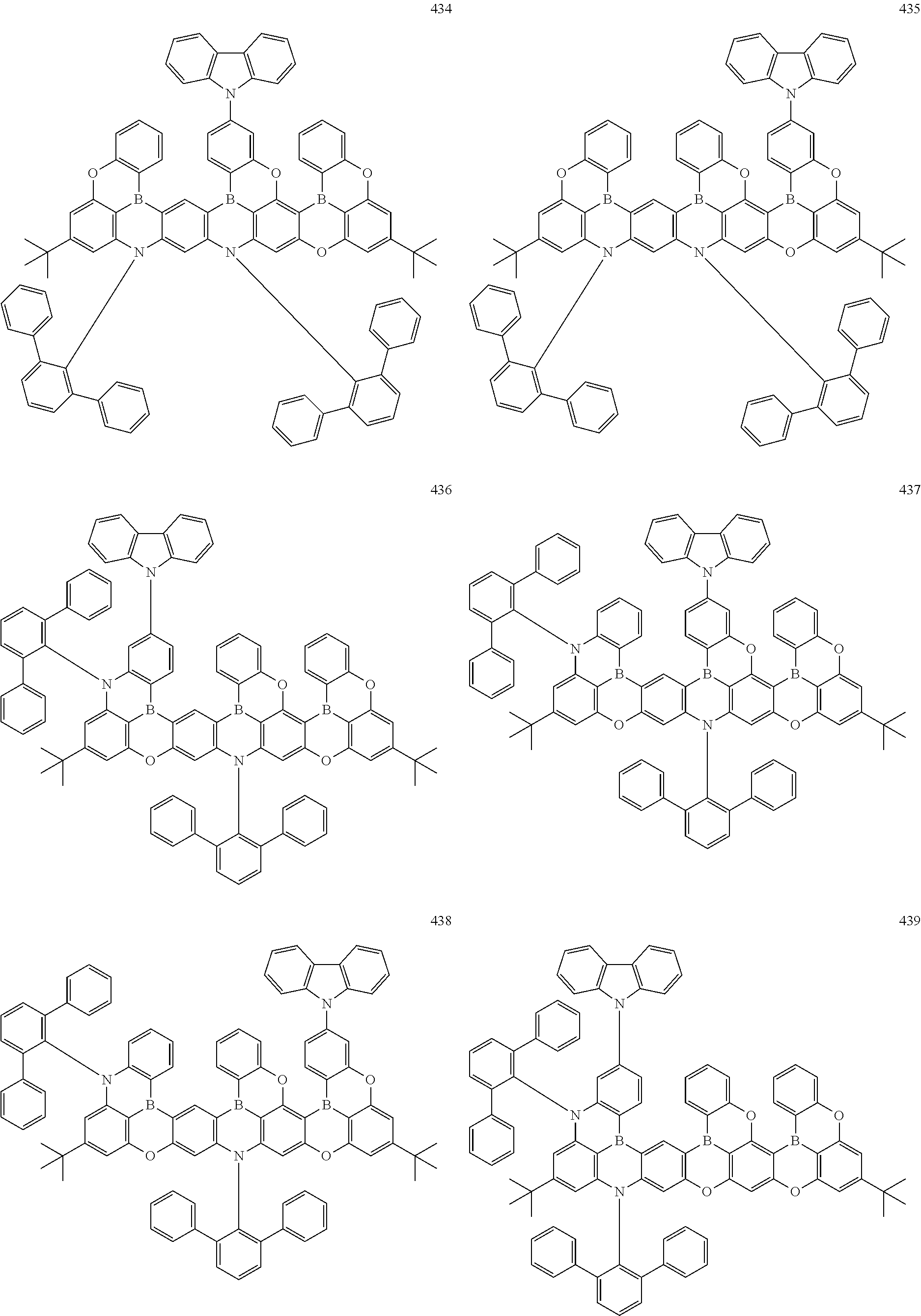

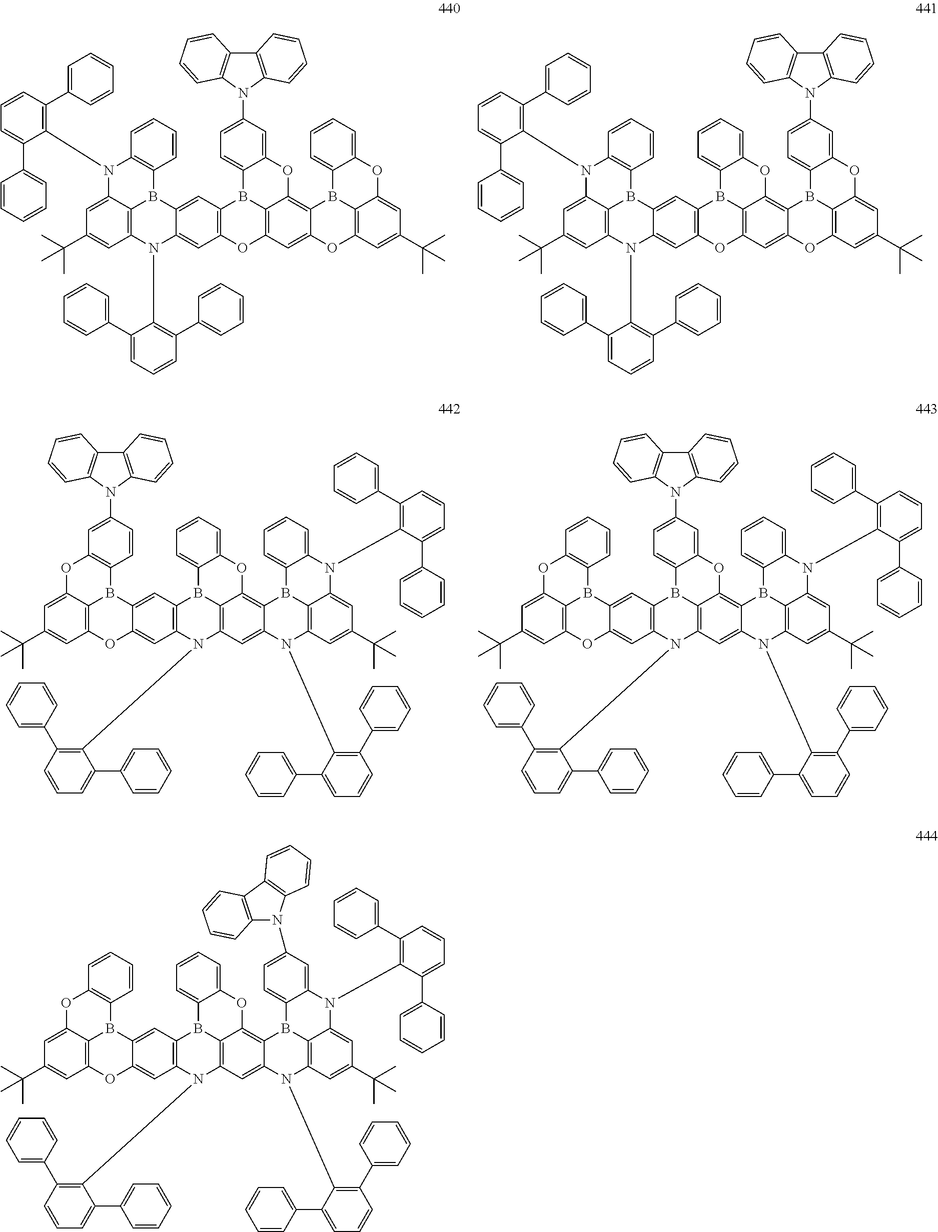

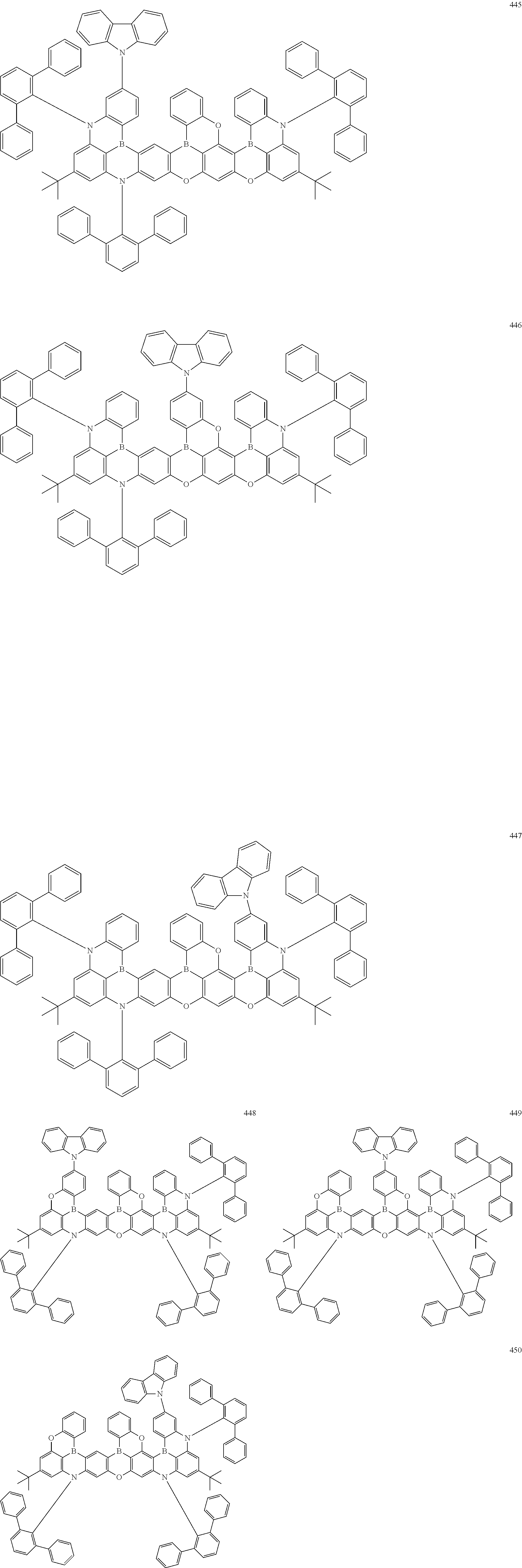

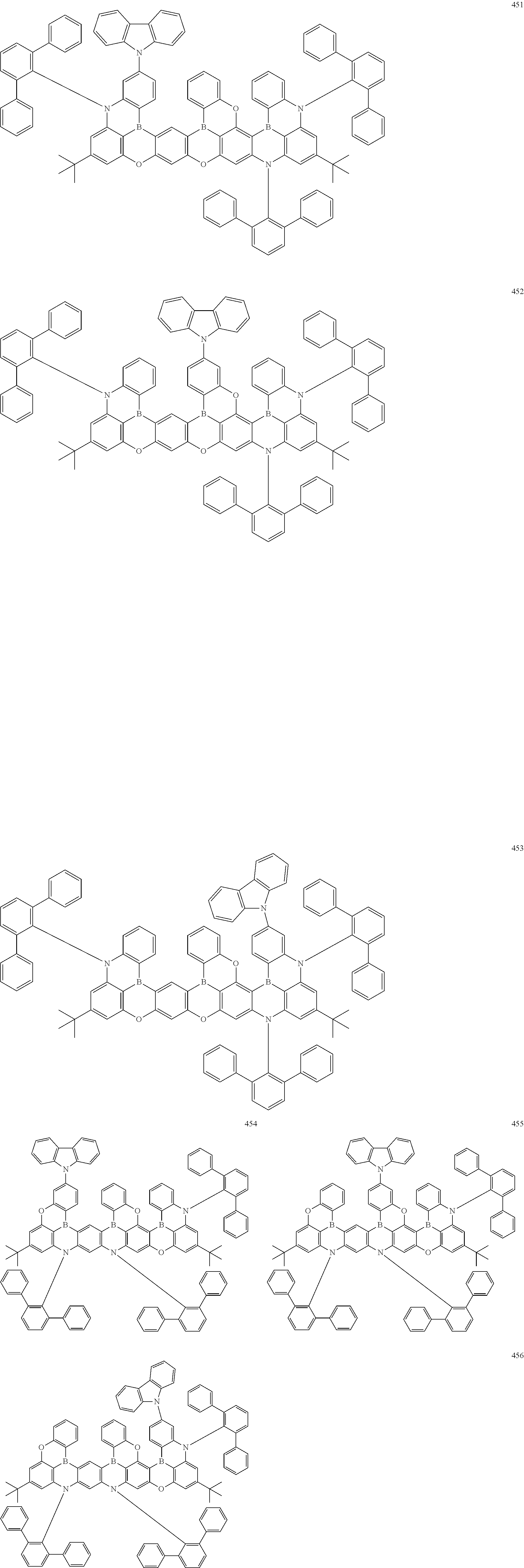

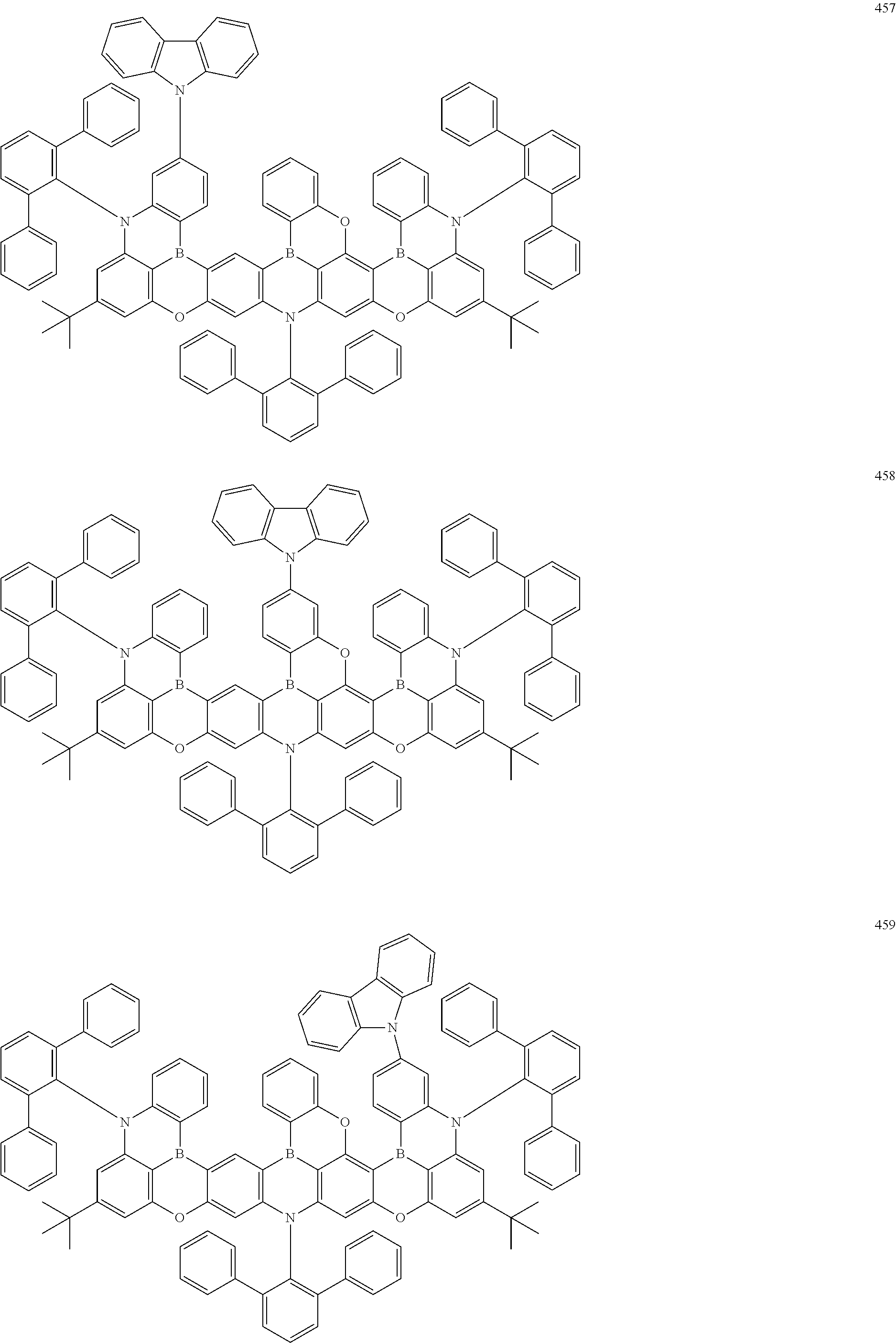

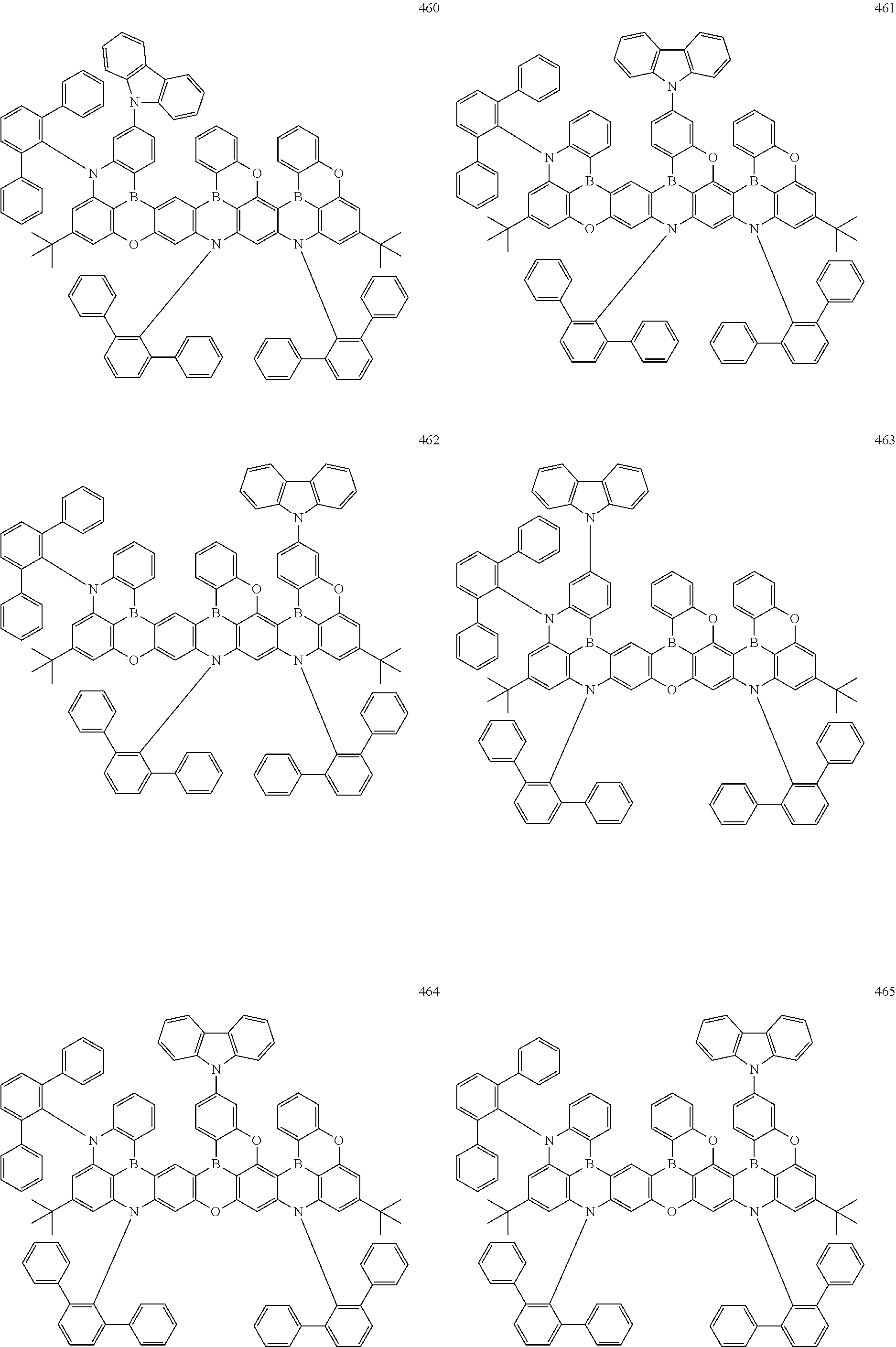

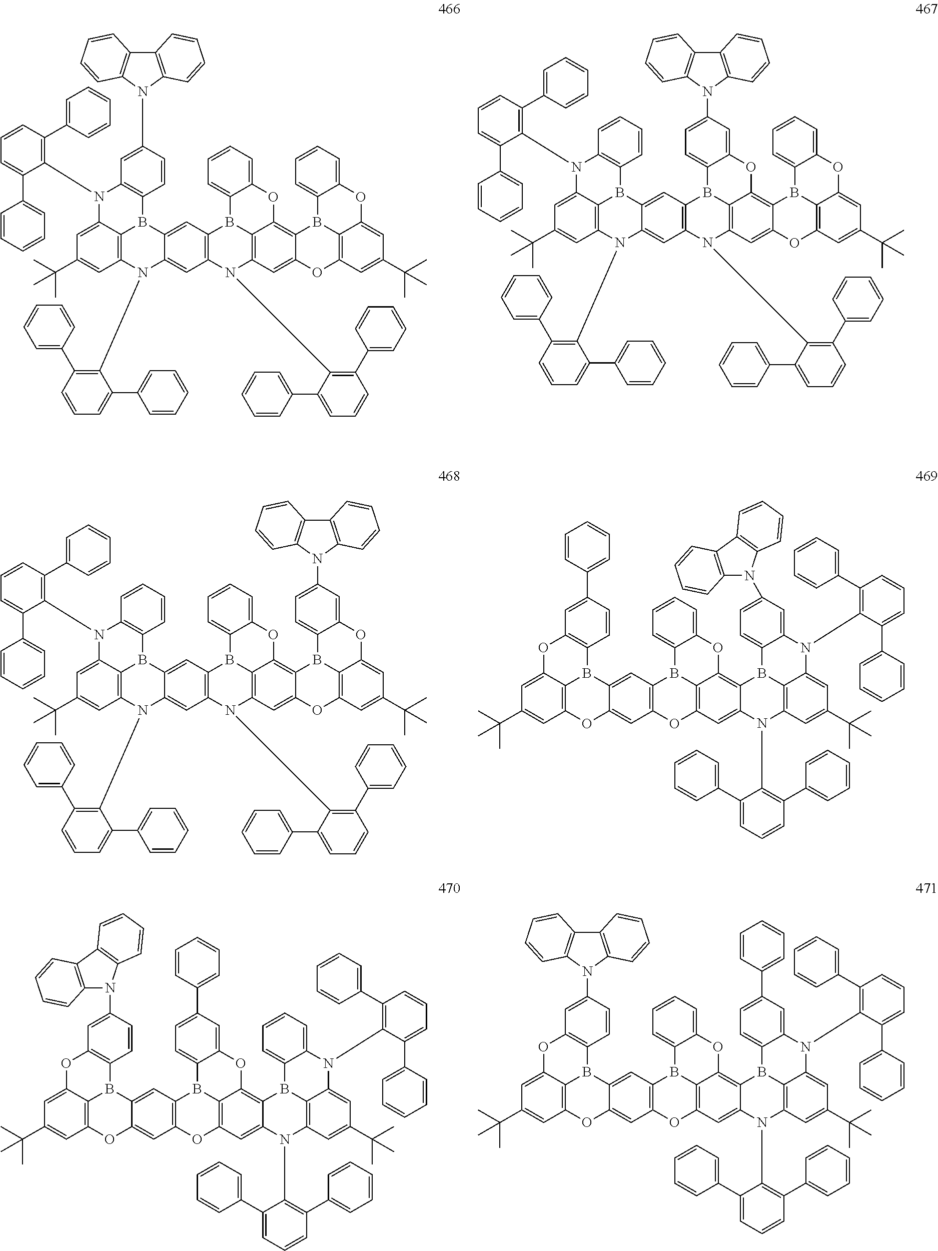

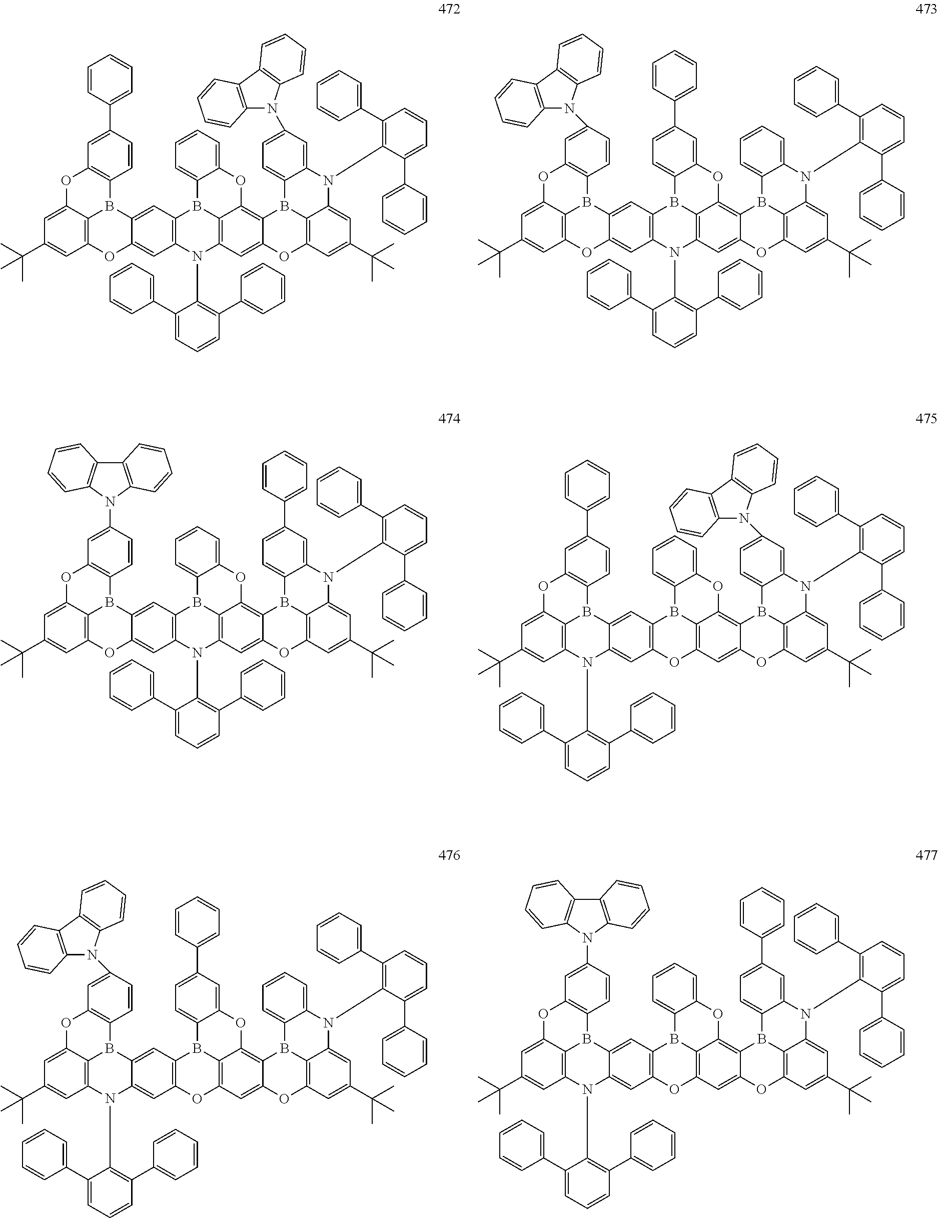

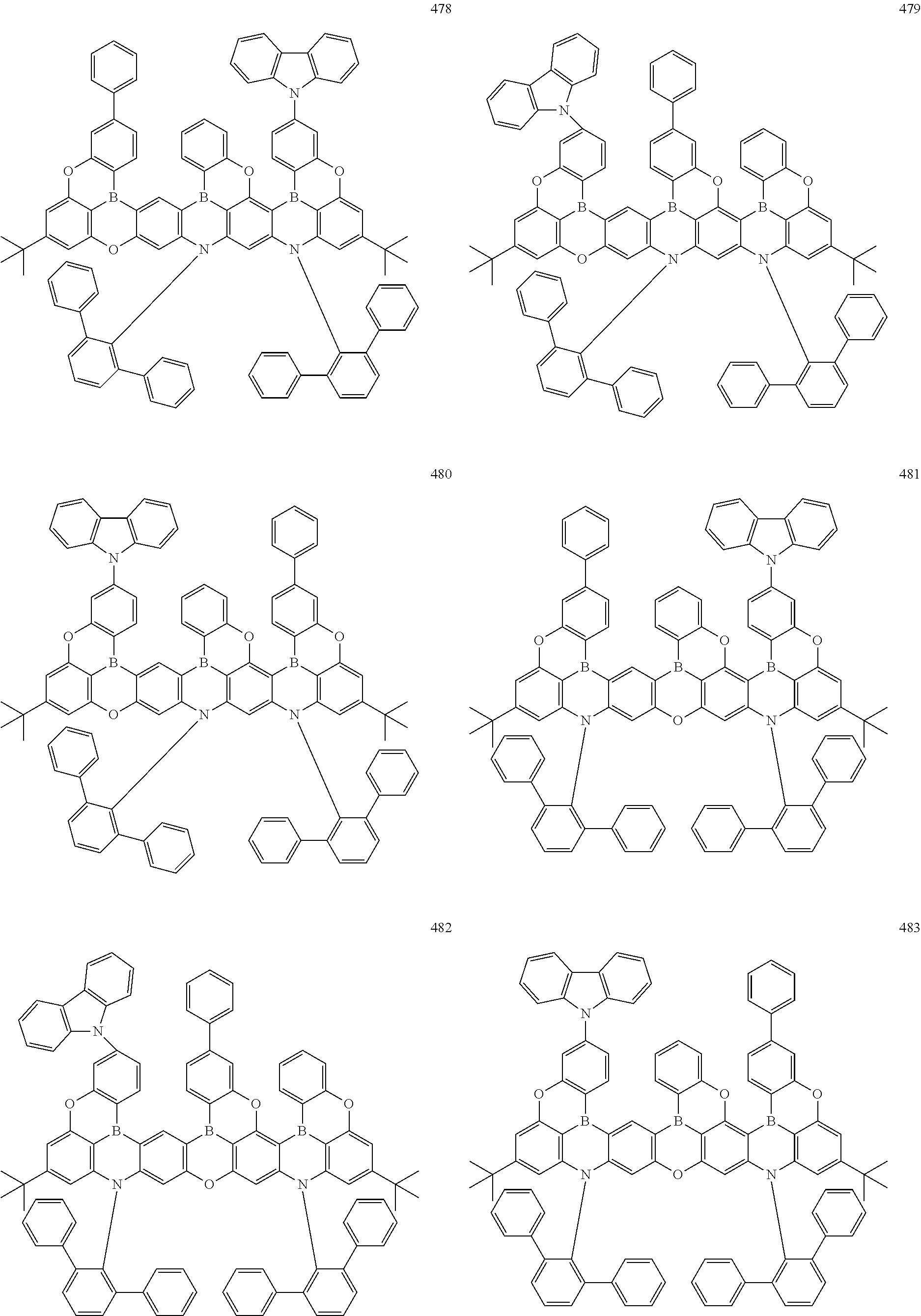

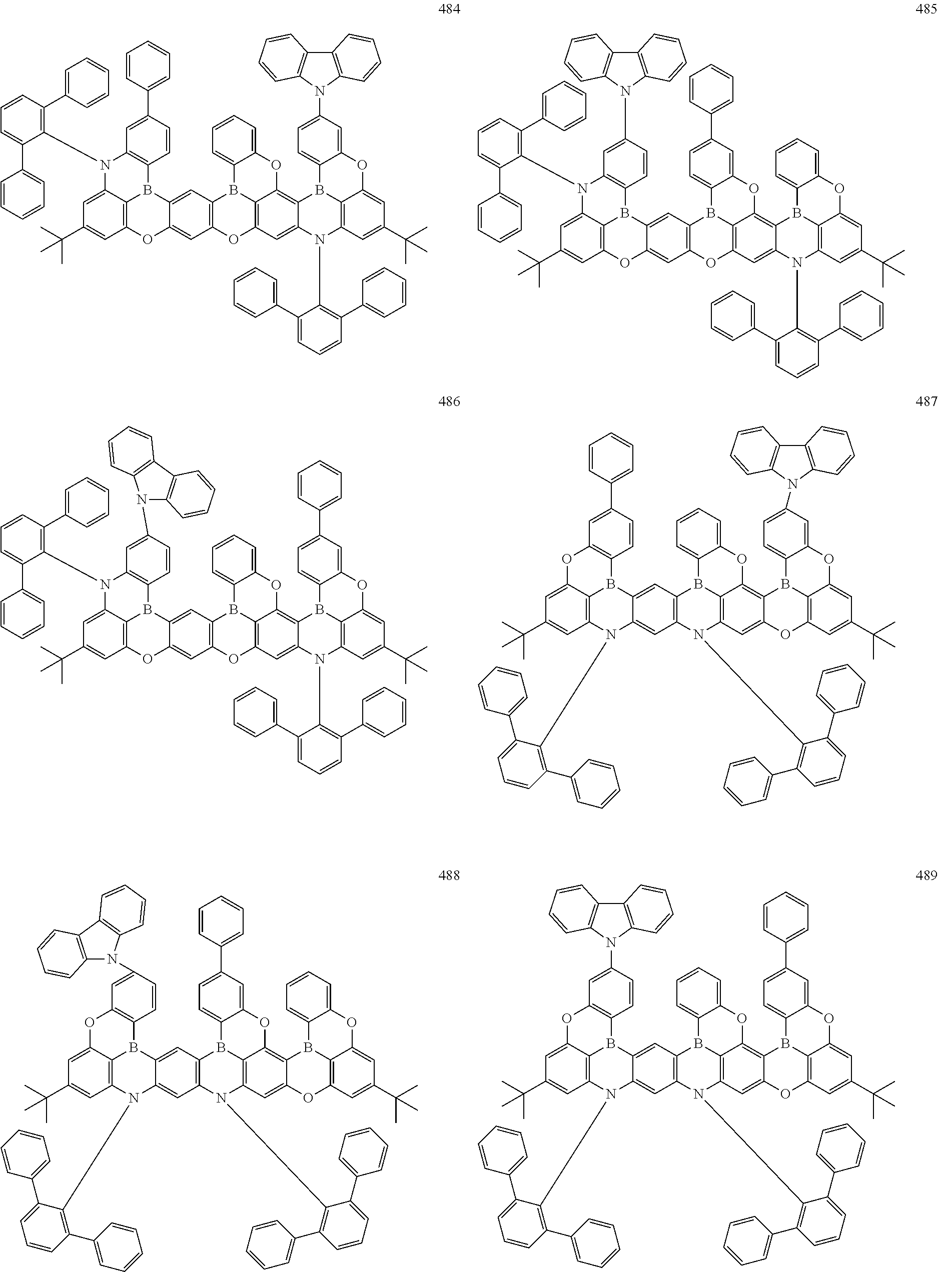

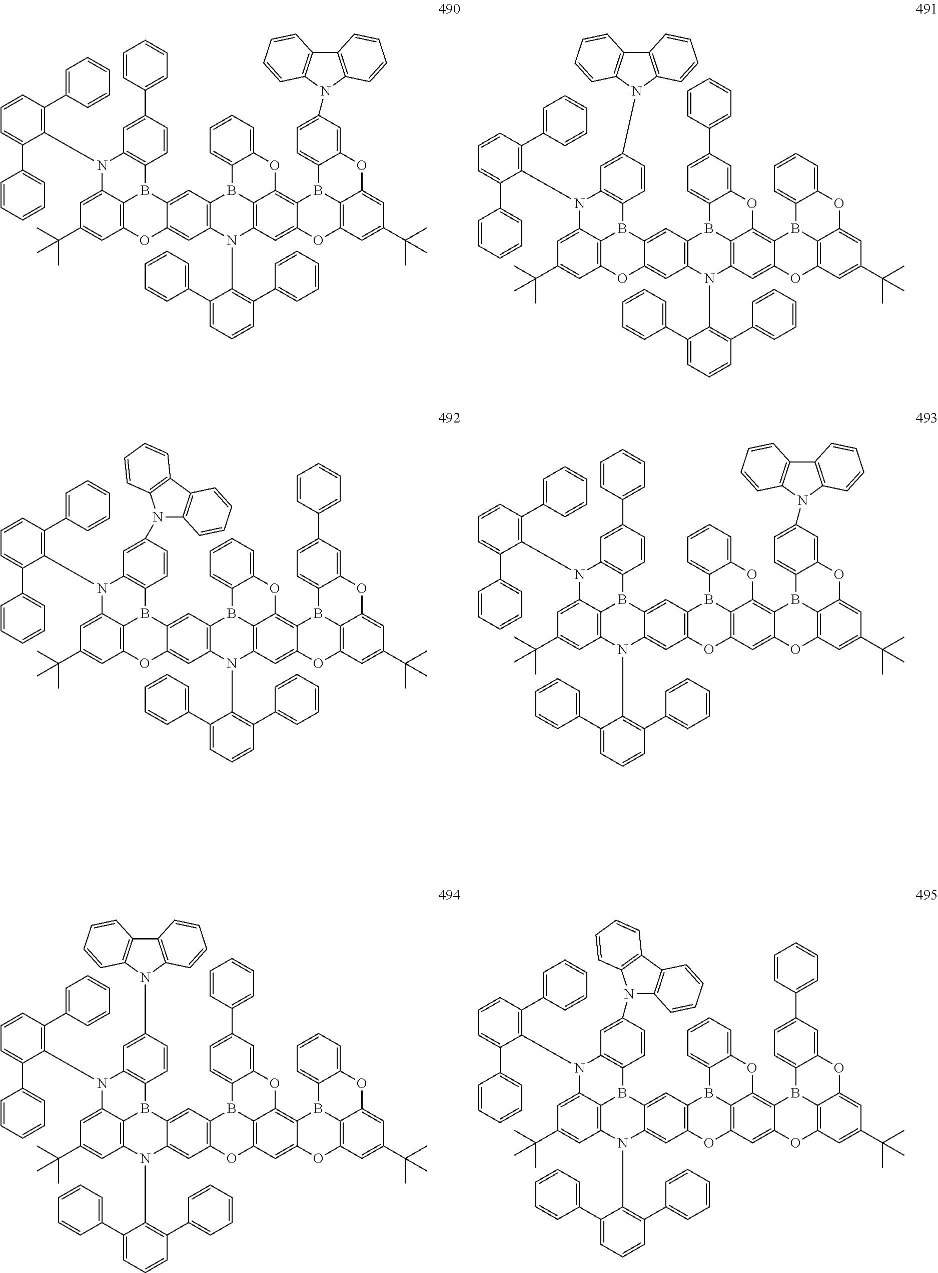

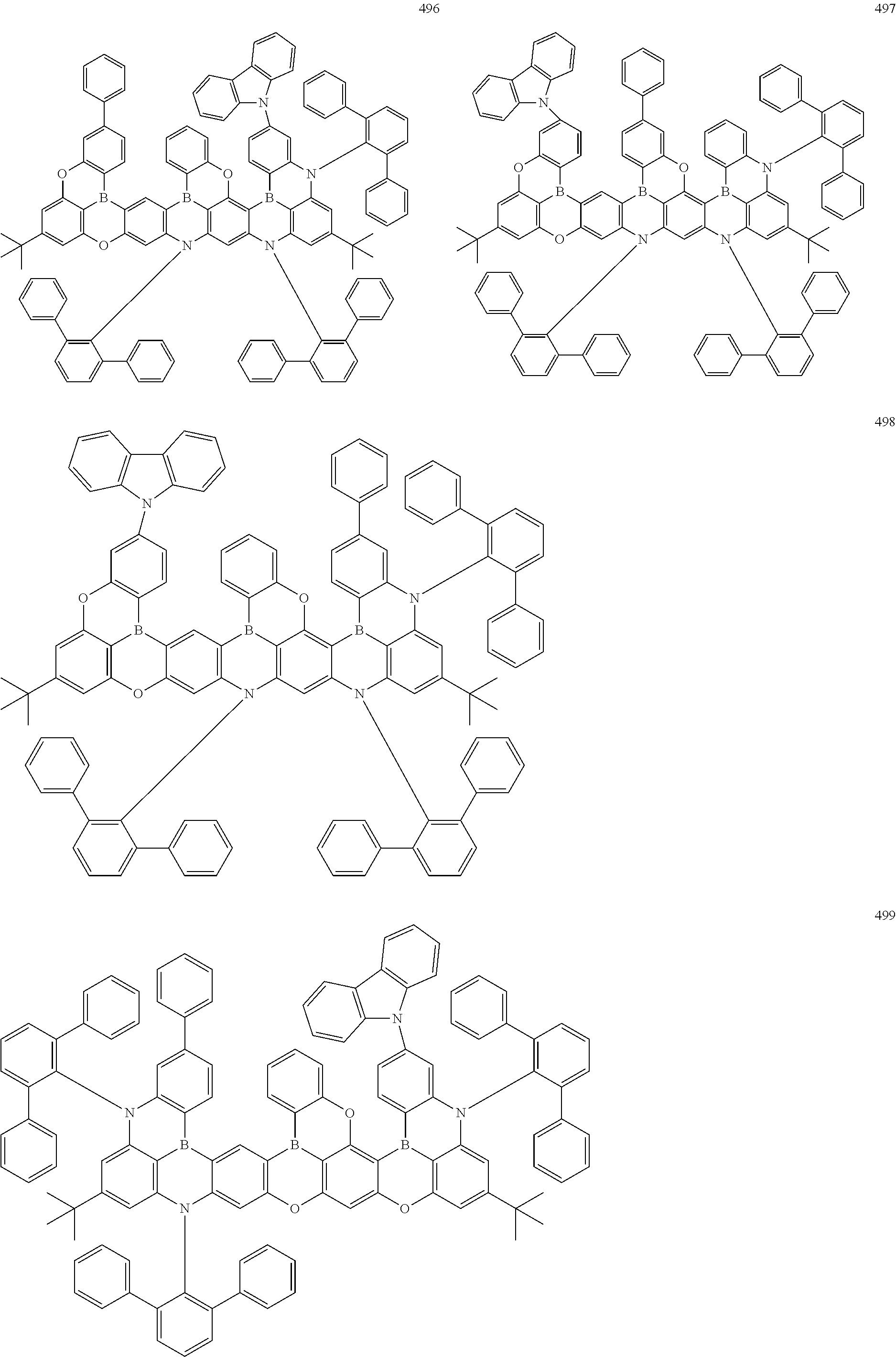

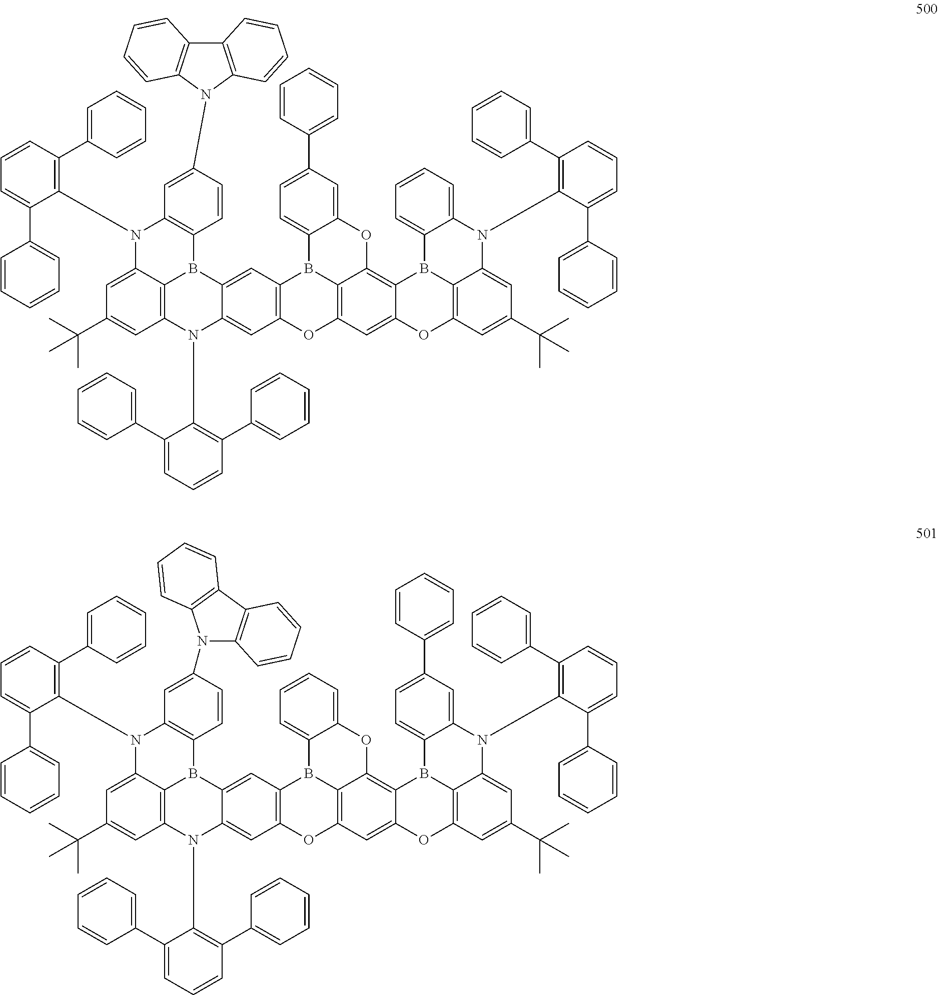 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1O3)N(c1c(-c3ccccc3)cccc1-c1ccccc1)c1cc(C(C)(C)C)cc3c1B4c1ccc(-n4c5ccccc5c5ccccc54)cc1N3c1c(-c3ccccc3)cccc1-c1ccccc1)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1O3)N(c1c(-c3ccccc3)cccc1-c1ccccc1)c1cc(C(C)(C)C)cc3c1B4c1ccc(-n4c5ccccc5c5ccccc54)cc1N3c1c(-c3ccccc3)cccc1-c1ccccc1)O2]

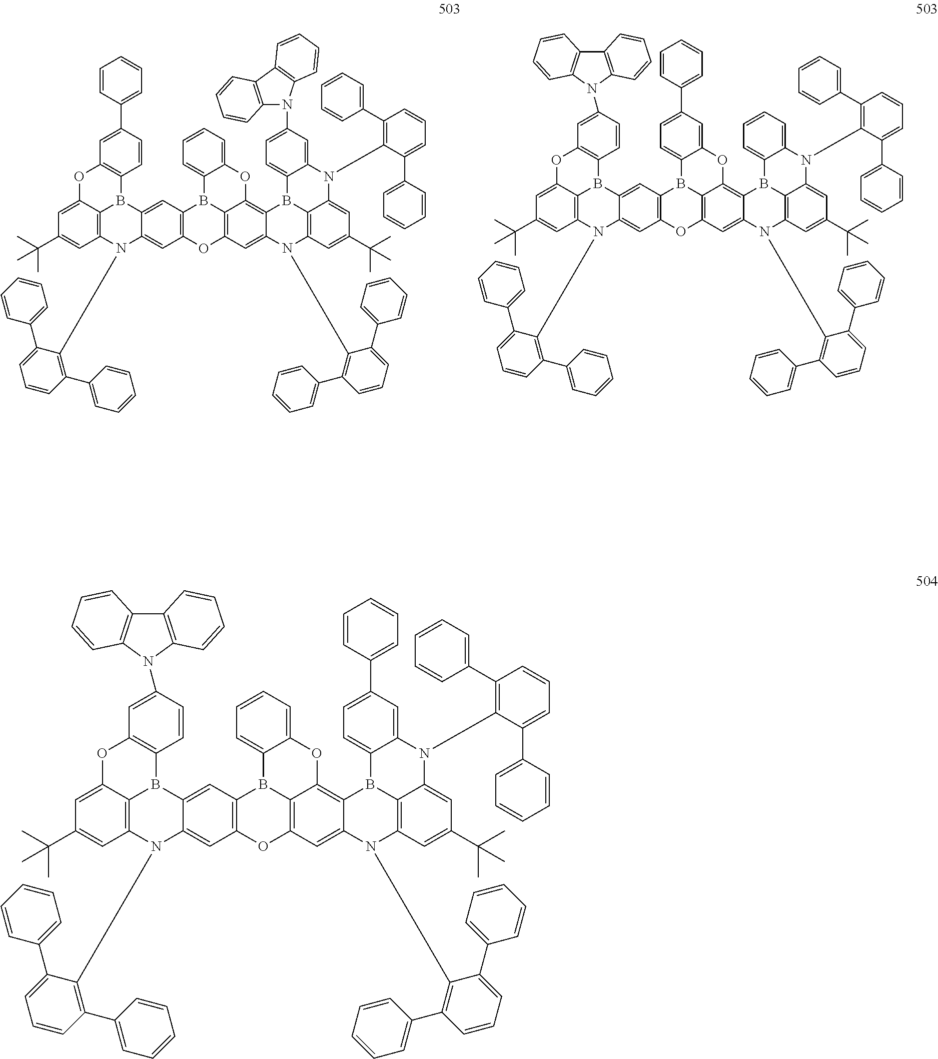

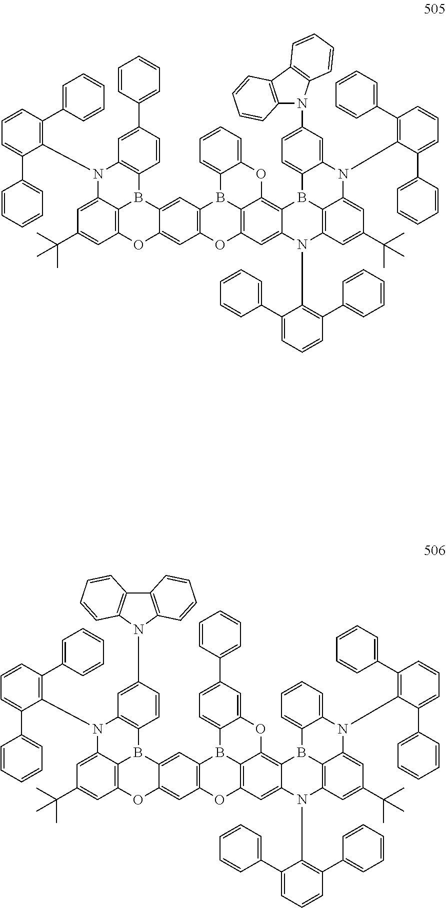 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccc(-n4c5ccccc5c5ccccc54)cc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)N2c1c(-c2ccccc2)cccc1-c1ccccc1]

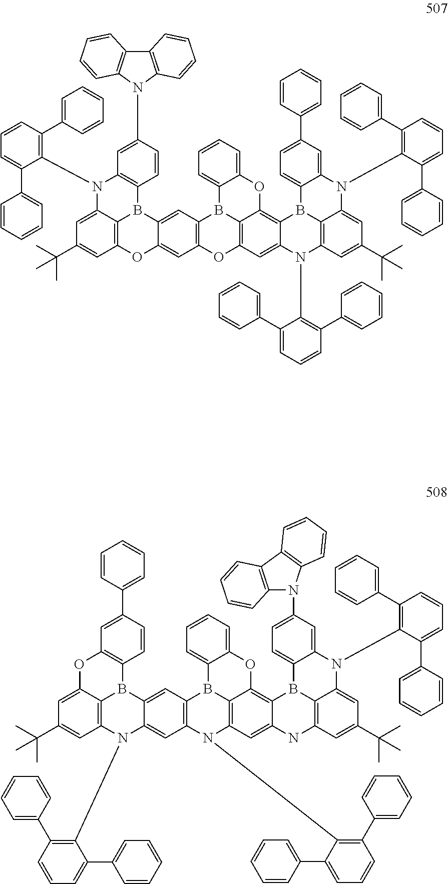 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(C(C)(C)C)cc3c1B4c1ccc(-c4ccccc4)cc1O3)N2]

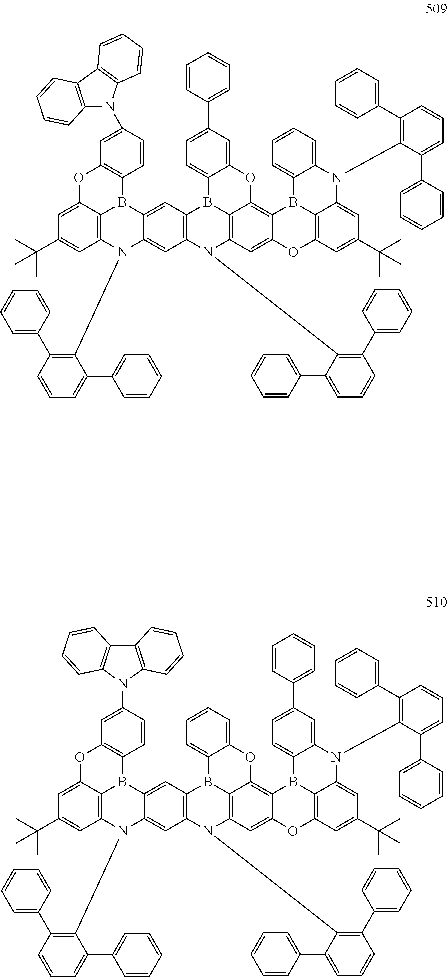 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1]

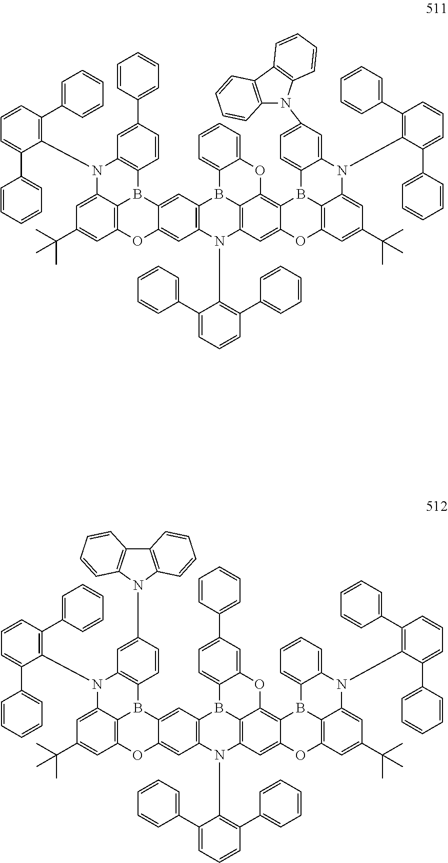 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)O2]

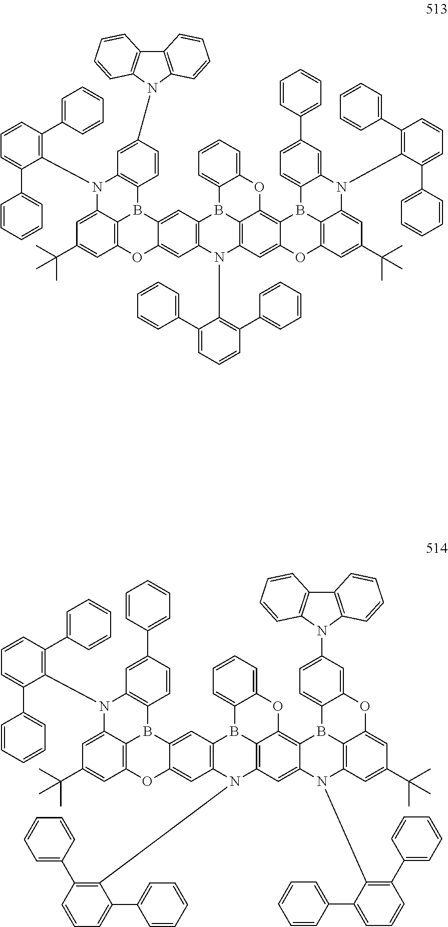 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3Oc3cc(C(C)(C)C)cc(c31)N2c1c(-c2ccccc2)cccc1-c1ccccc1]

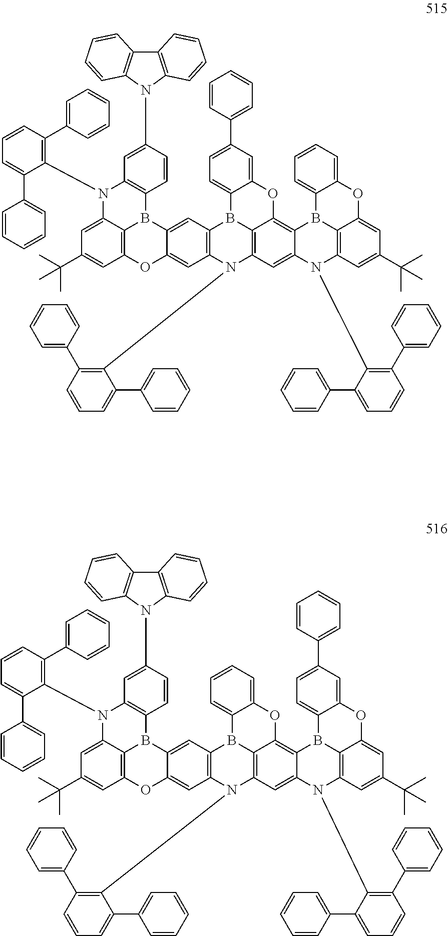 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3Oc3cc(C(C)(C)C)cc(c31)N2c1c(-c2ccccc2)cccc1-c1ccccc1]

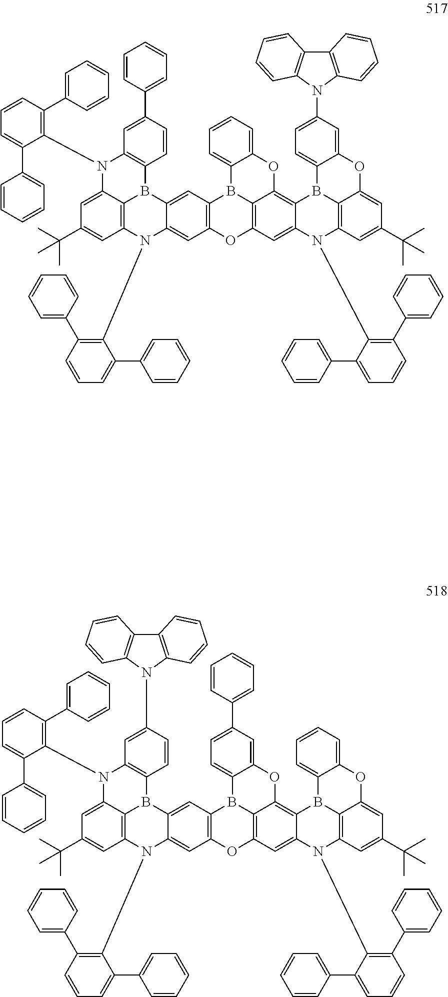 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1]

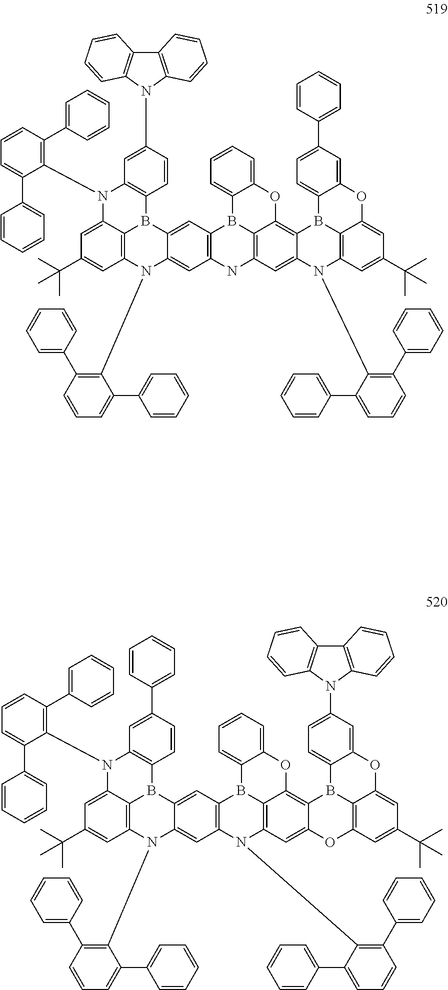 [SMILES: CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1N4)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1]

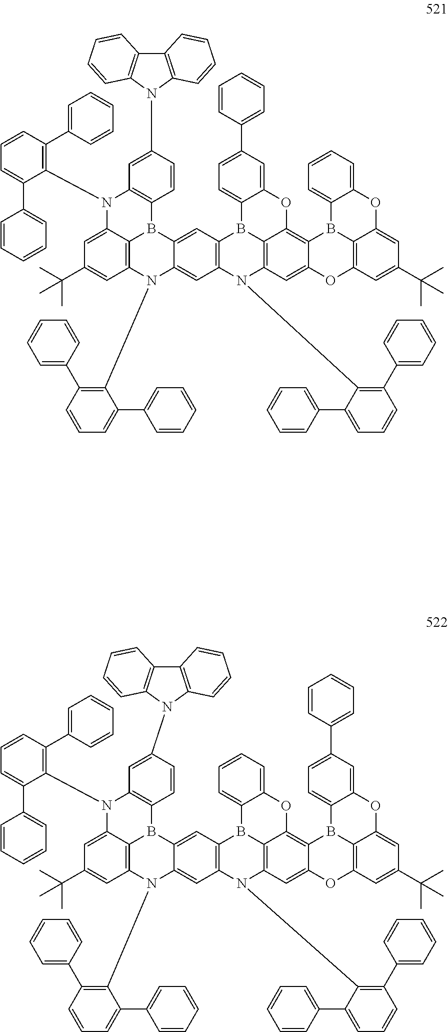 [SMILES: CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1]

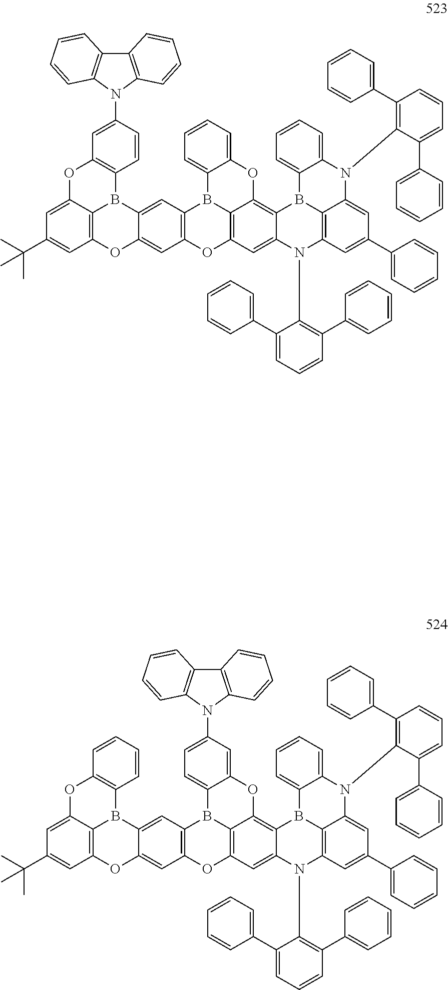 [SMILES: CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)Oc1cc4c(cc1B3c1ccccc1O2)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4]

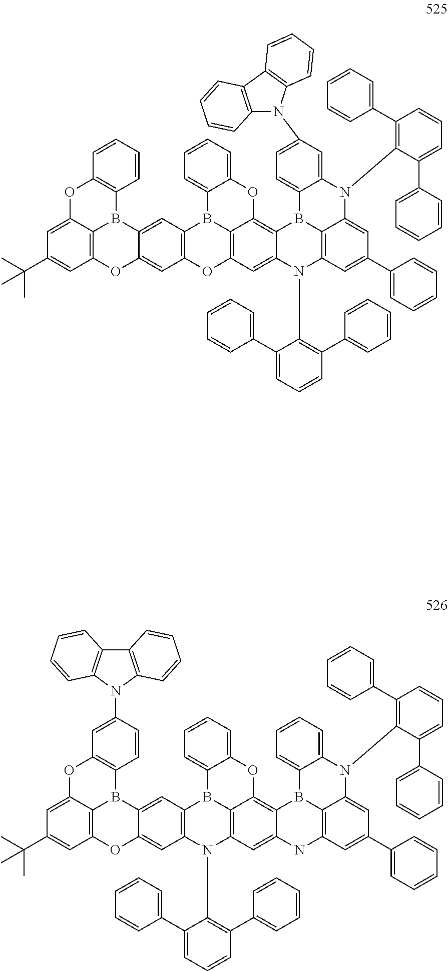 [SMILES: CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)Oc1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Nc1cc(-c2ccccc2)cc2c1B3c1ccccc1N2c1c(-c2ccccc2)cccc1-c1ccccc1]

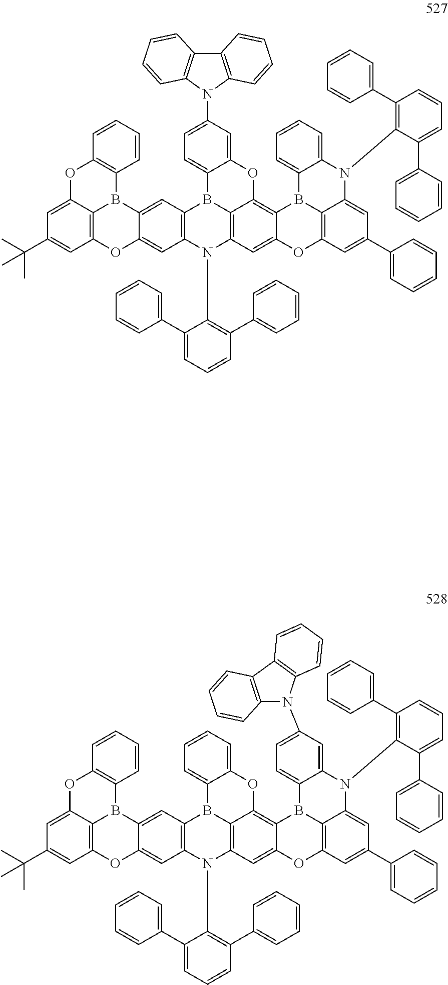 [SMILES: CC(C)(C)c1cc2c3c(c1)Oc1cc4c(cc1B3c1ccccc1O2)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1N2c1c(-c2ccccc2)cccc1-c1ccccc1]

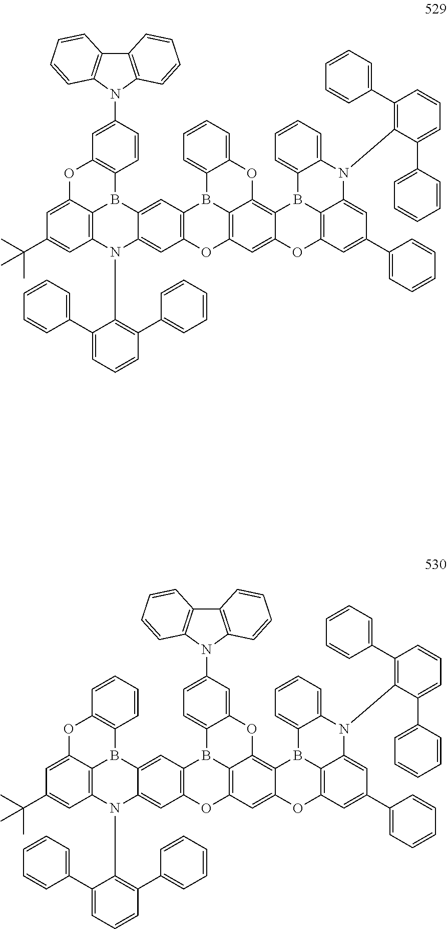 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c1c(cc1c2B2c3ccccc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)O1)O4]

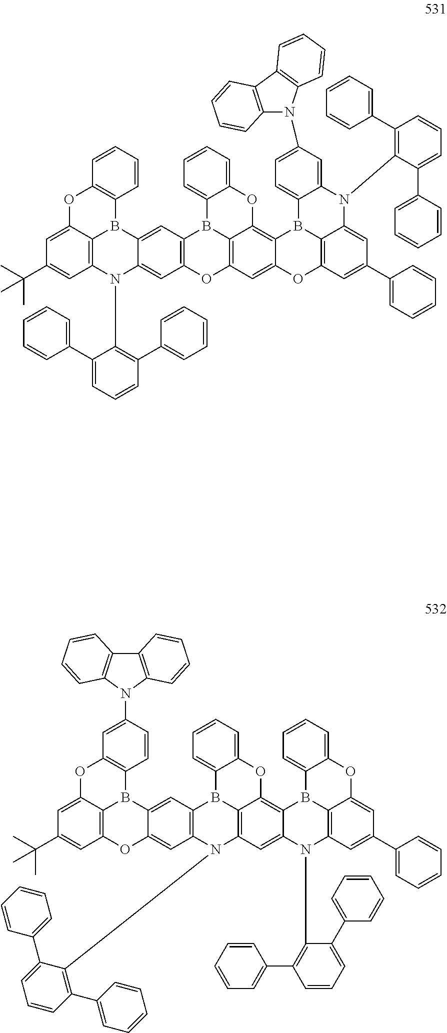 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)O1)O4 ; CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccccc3Oc3cc(-c5ccccc5)cc(c32)N1c1c(-c2ccccc2)cccc1-c1ccccc1)N4c1c(-c2ccccc2)cccc1-c1ccccc1]

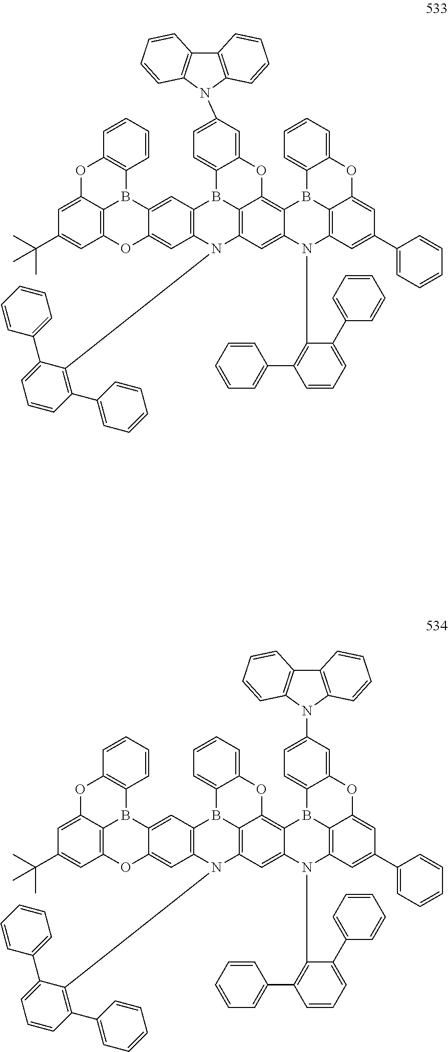 [SMILES: CC(C)(C)c1cc2c3c(c1)Oc1cc4c(cc1B3c1ccccc1O2)B1c2ccc(-n3c5ccccc5c5ccccc53)cc2Oc2c1c(cc1c2B2c3ccccc3Oc3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3Oc3cc(-c5ccccc5)cc(c32)N1c1c(-c2ccccc2)cccc1-c1ccccc1)N4c1c(-c2ccccc2)cccc1-c1ccccc1]

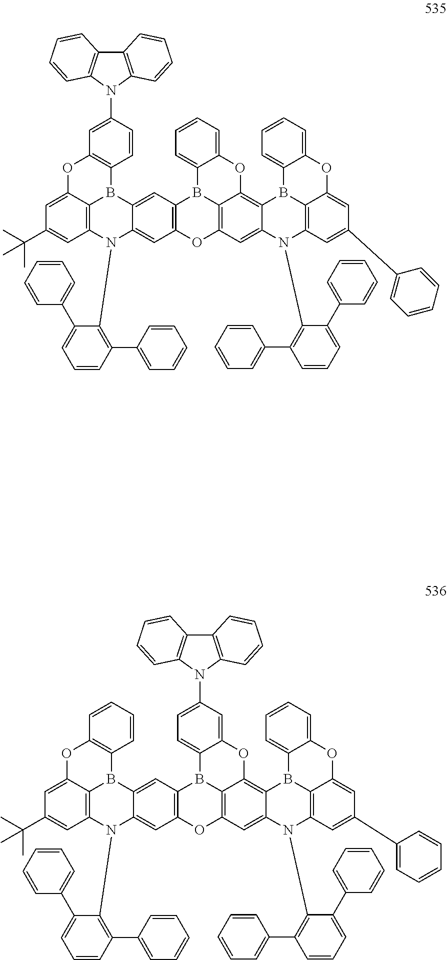 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c1c(cc1c2B2c3ccccc3Oc3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c1c(cc1c2B2c3ccccc3Oc3cc(-c5ccccc5)cc(c32)N1c1c(-c2ccccc2)cccc1-c1ccccc1)O4]

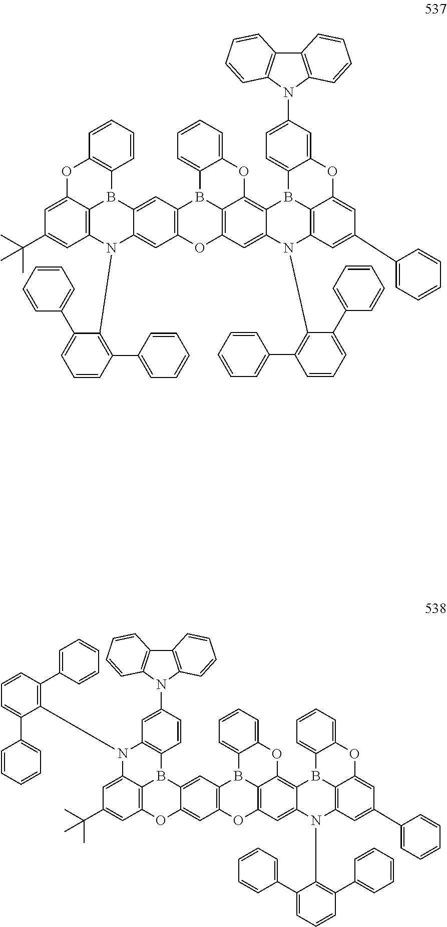 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-n5c6ccccc6c6ccccc65)cc3Oc3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccccc3Oc3cc(-c4ccccc4)cc(c31)N2c1c(-c2ccccc2)cccc1-c1ccccc1]

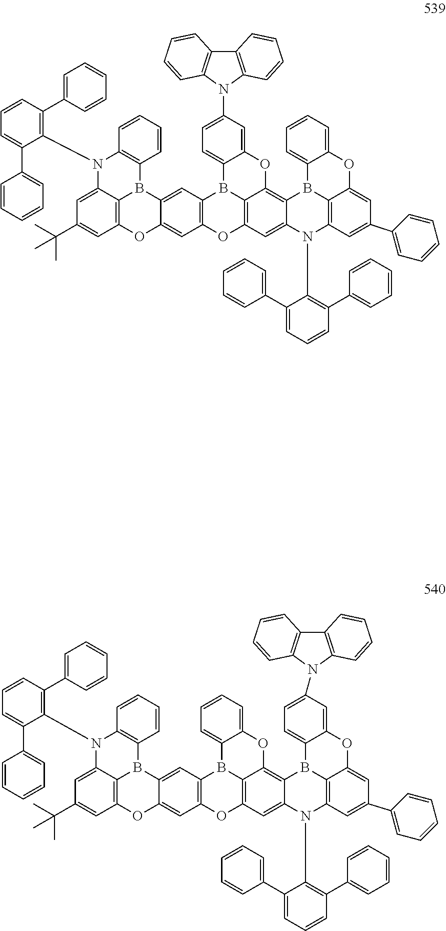 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-n3c5ccccc5c5ccccc53)cc1O4)B1c3ccccc3Oc3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-n4c5ccccc5c5ccccc54)cc3Oc3cc(-c4ccccc4)cc(c31)N2c1c(-c2ccccc2)cccc1-c1ccccc1]

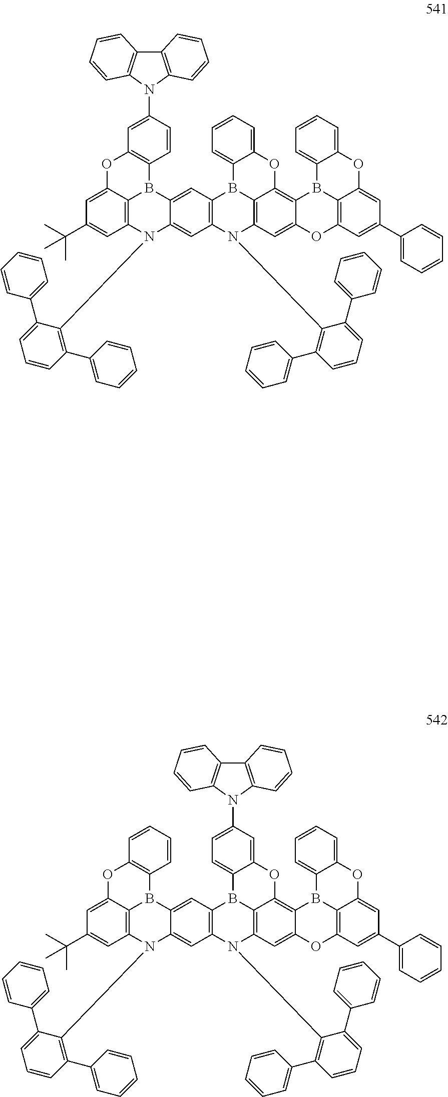 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1O2]

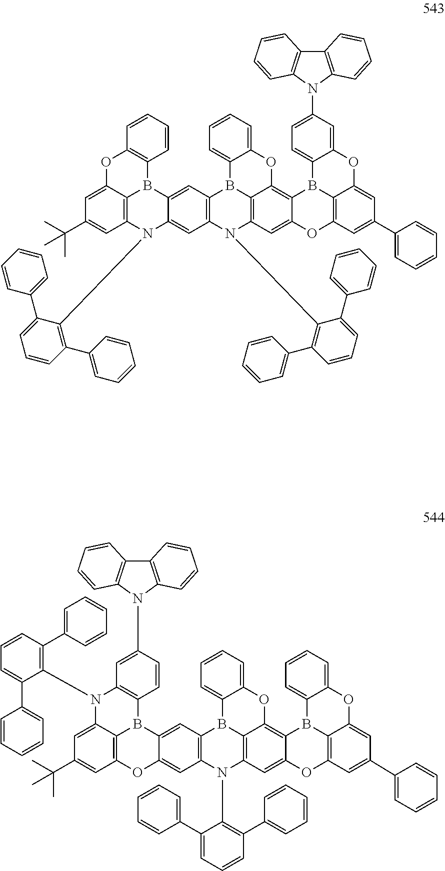 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccccc3Oc3cc(-c4ccccc4)cc(c31)O2]

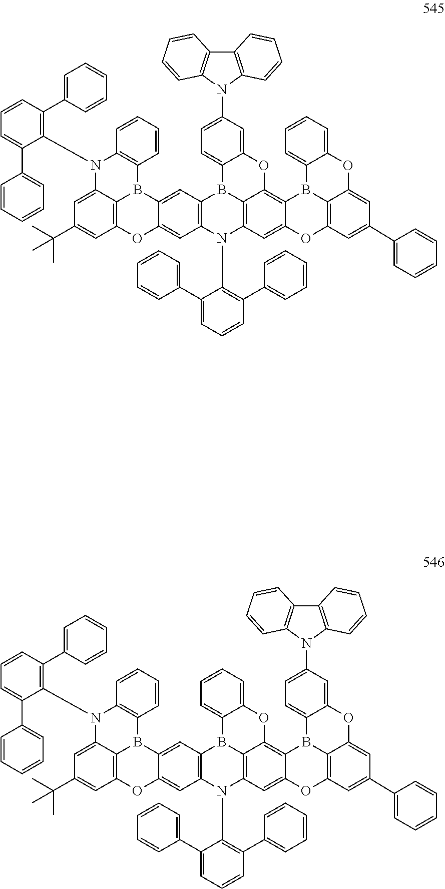 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc2c(c4c1B3c1ccc(-n3c5ccccc5c5ccccc53)cc1O4)B1c3ccccc3Oc3cc(-c4ccccc4)cc(c31)O2 ; CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3Oc3cc(-c4ccccc4)cc(c31)O2]

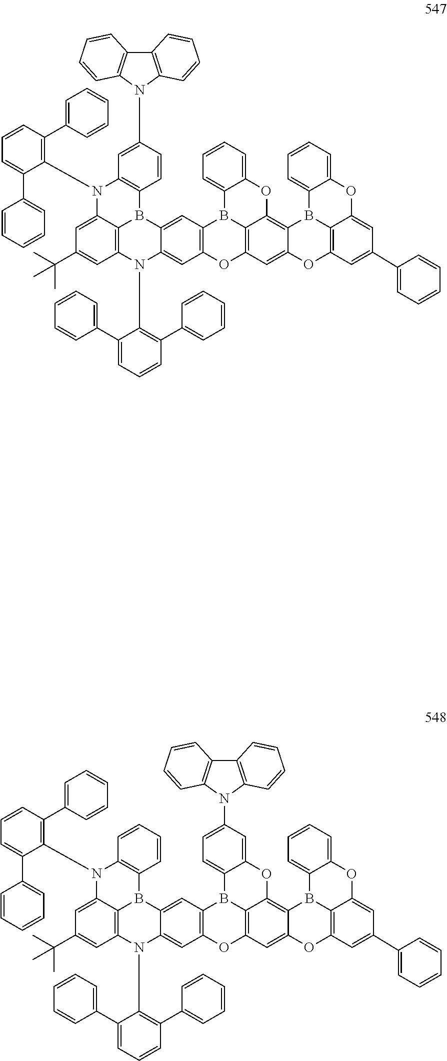 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c1c(cc1c2B2c3ccccc3Oc3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-n3c5ccccc5c5ccccc53)cc2Oc2c1c(cc1c2B2c3ccccc3Oc3cc(-c5ccccc5)cc(c32)O1)O4]

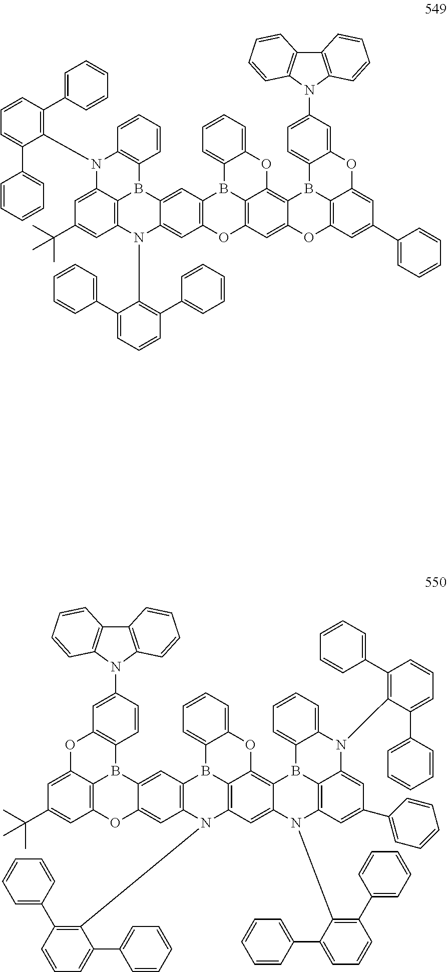 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c1c(cc1c2B2c3ccc(-n5c6ccccc6c6ccccc65)cc3Oc3cc(-c5ccccc5)cc(c32)O1)O4 ; CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1]

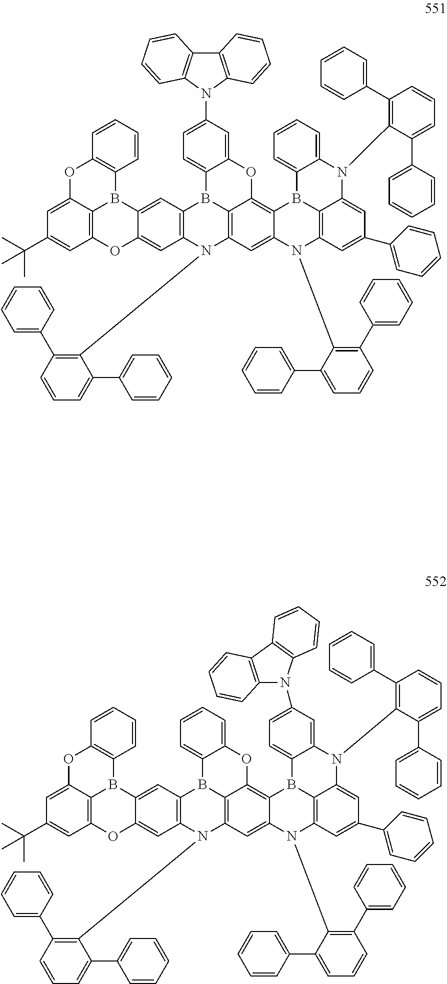 [SMILES: CC(C)(C)c1cc2c3c(c1)Oc1cc4c(cc1B3c1ccccc1O2)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1]

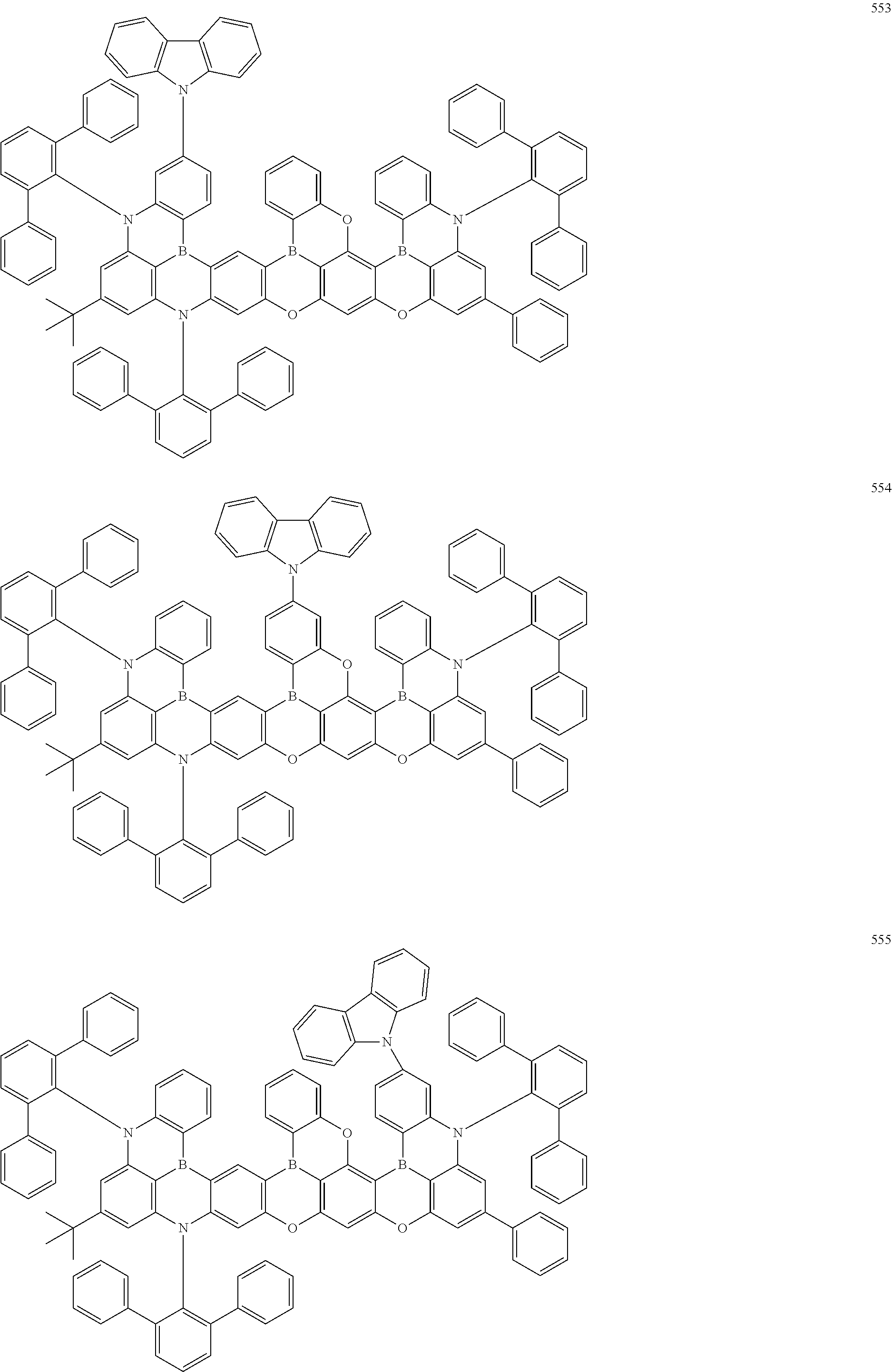

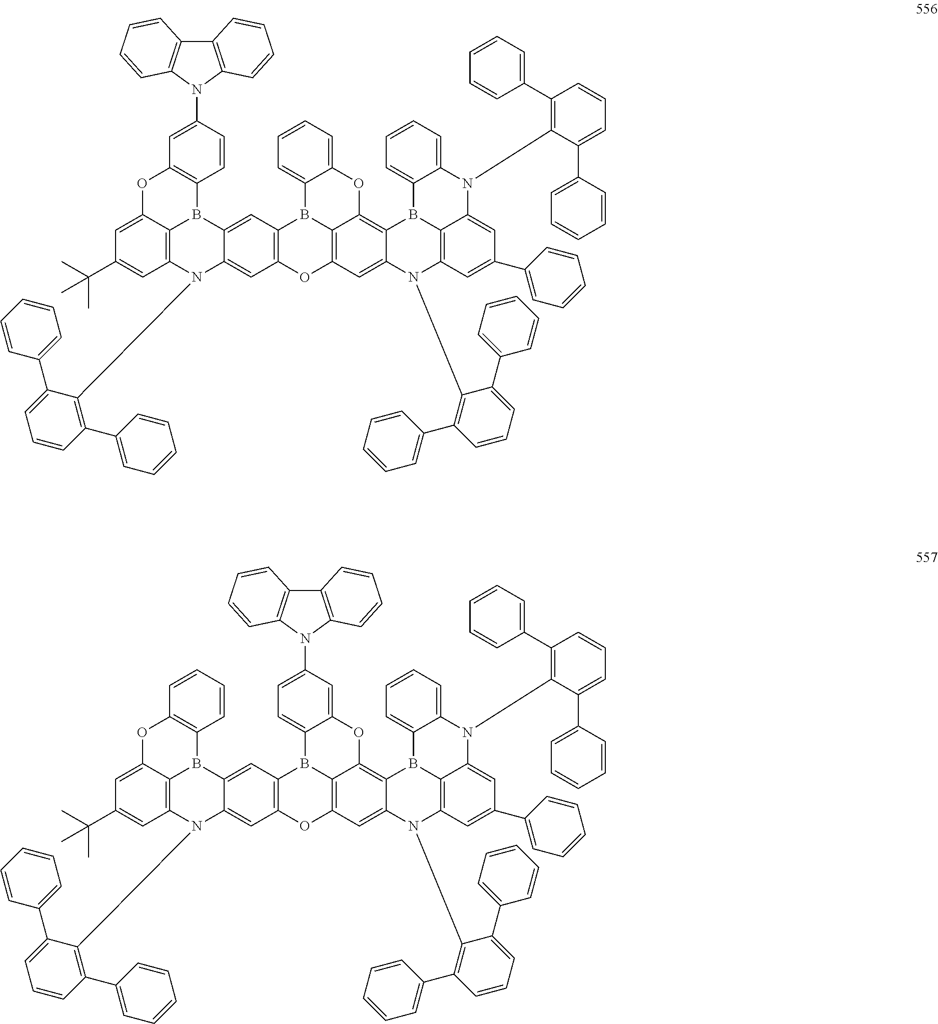 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4]

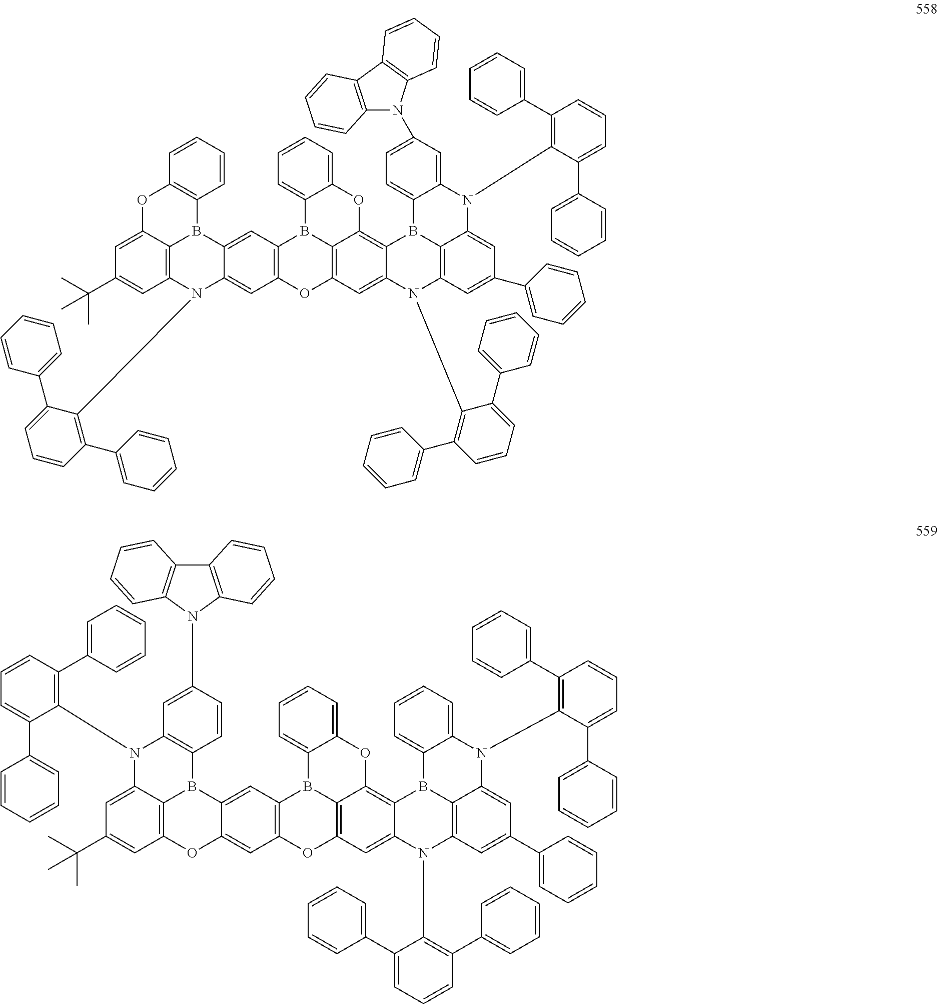 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccccc3N(c3c(-c4ccccc4)cccc3-c3ccccc3)c3cc(-c4ccccc4)cc(c31)N2c1c(-c2ccccc2)cccc1-c1ccccc1]

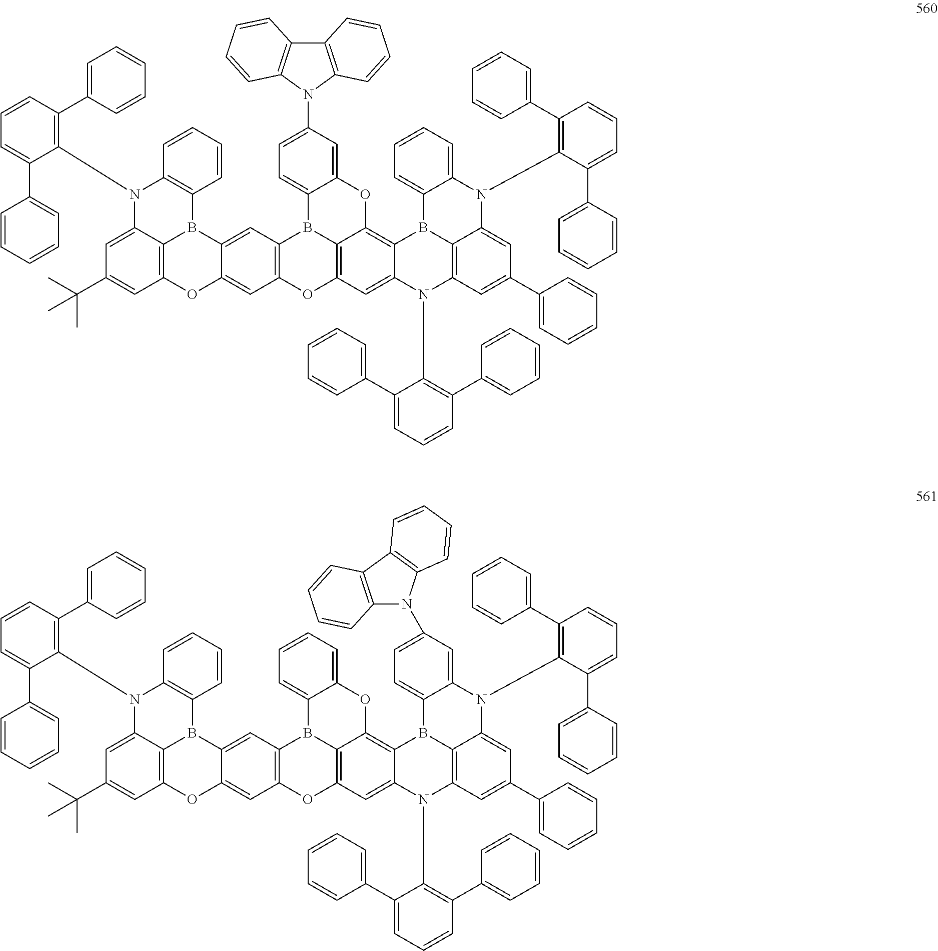 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-n3c5ccccc5c5ccccc53)cc1O4)B1c3ccccc3N(c3c(-c4ccccc4)cccc3-c3ccccc3)c3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-n4c5ccccc5c5ccccc54)cc3N(c3c(-c4ccccc4)cccc3-c3ccccc3)c3cc(-c4ccccc4)cc(c31)N2c1c(-c2ccccc2)cccc1-c1ccccc1]

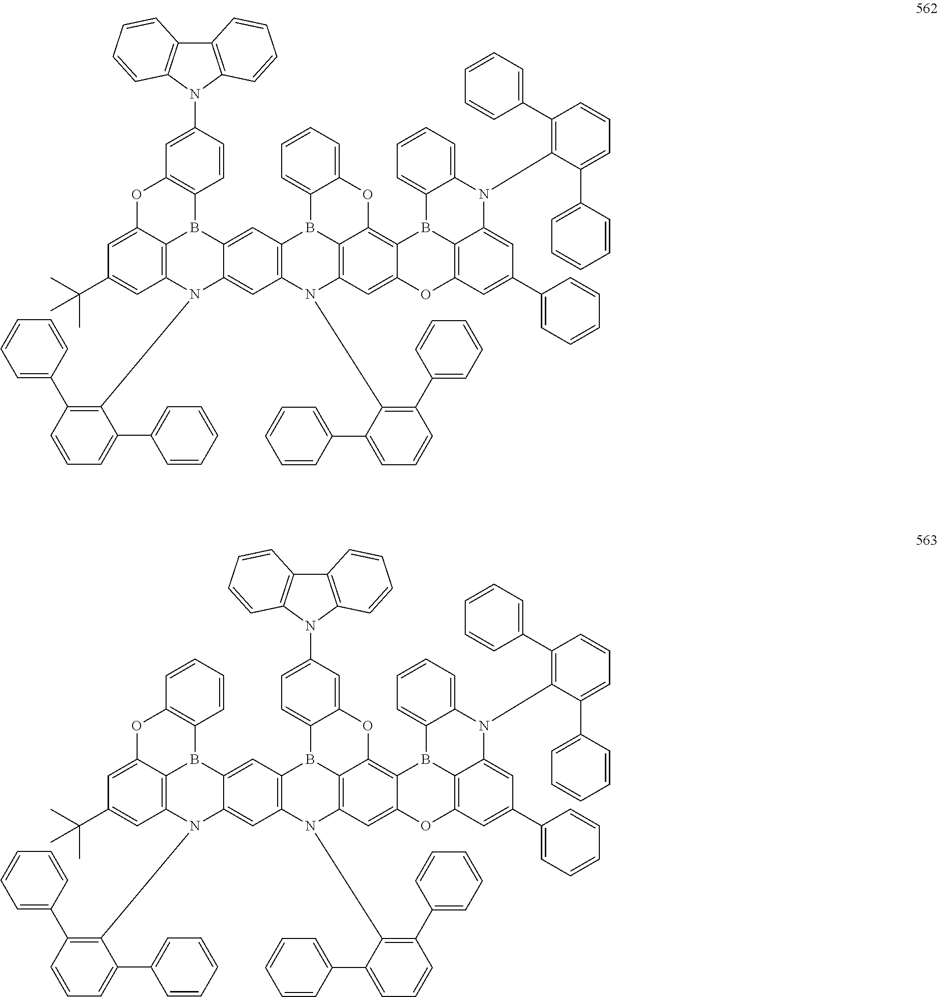 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1]

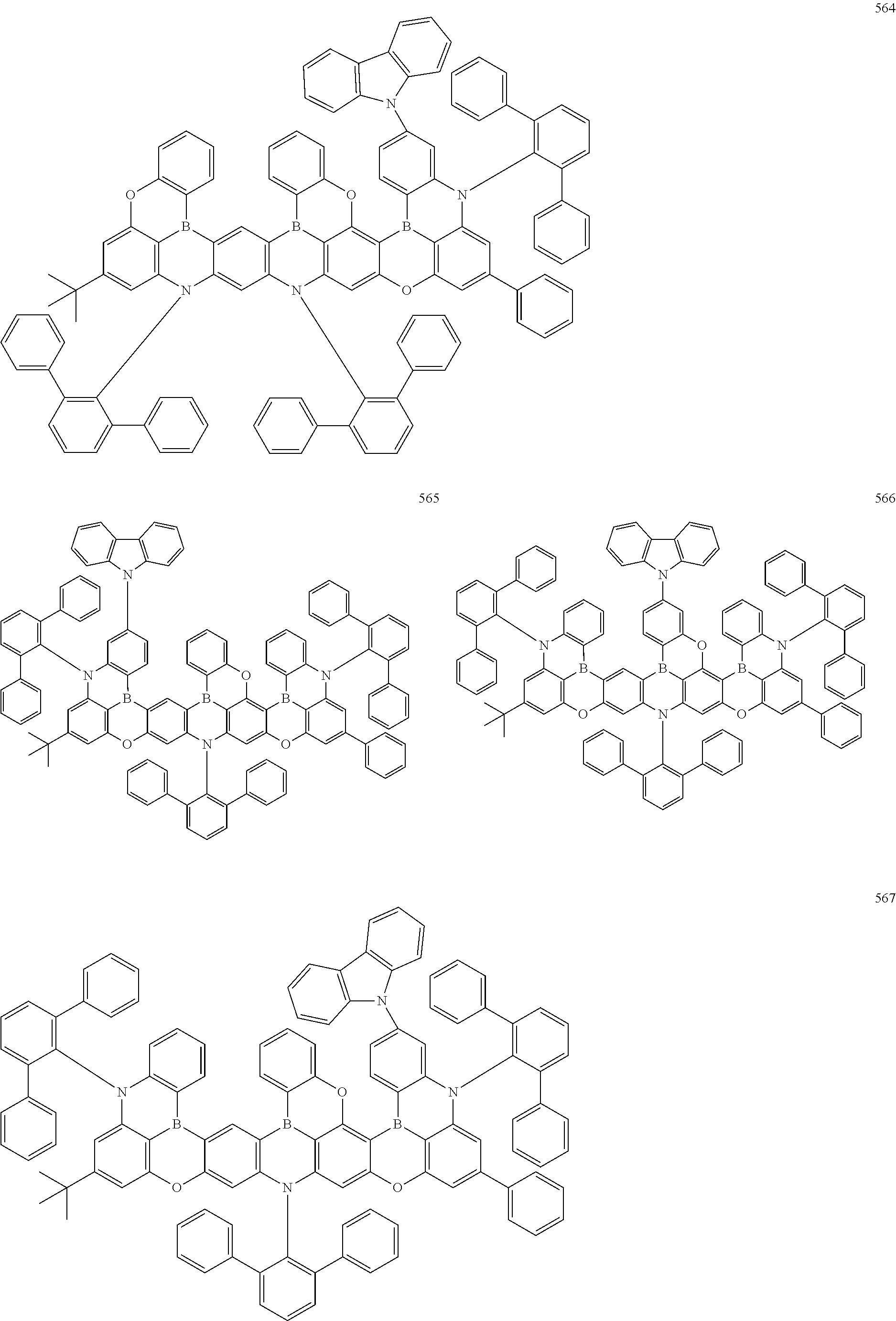

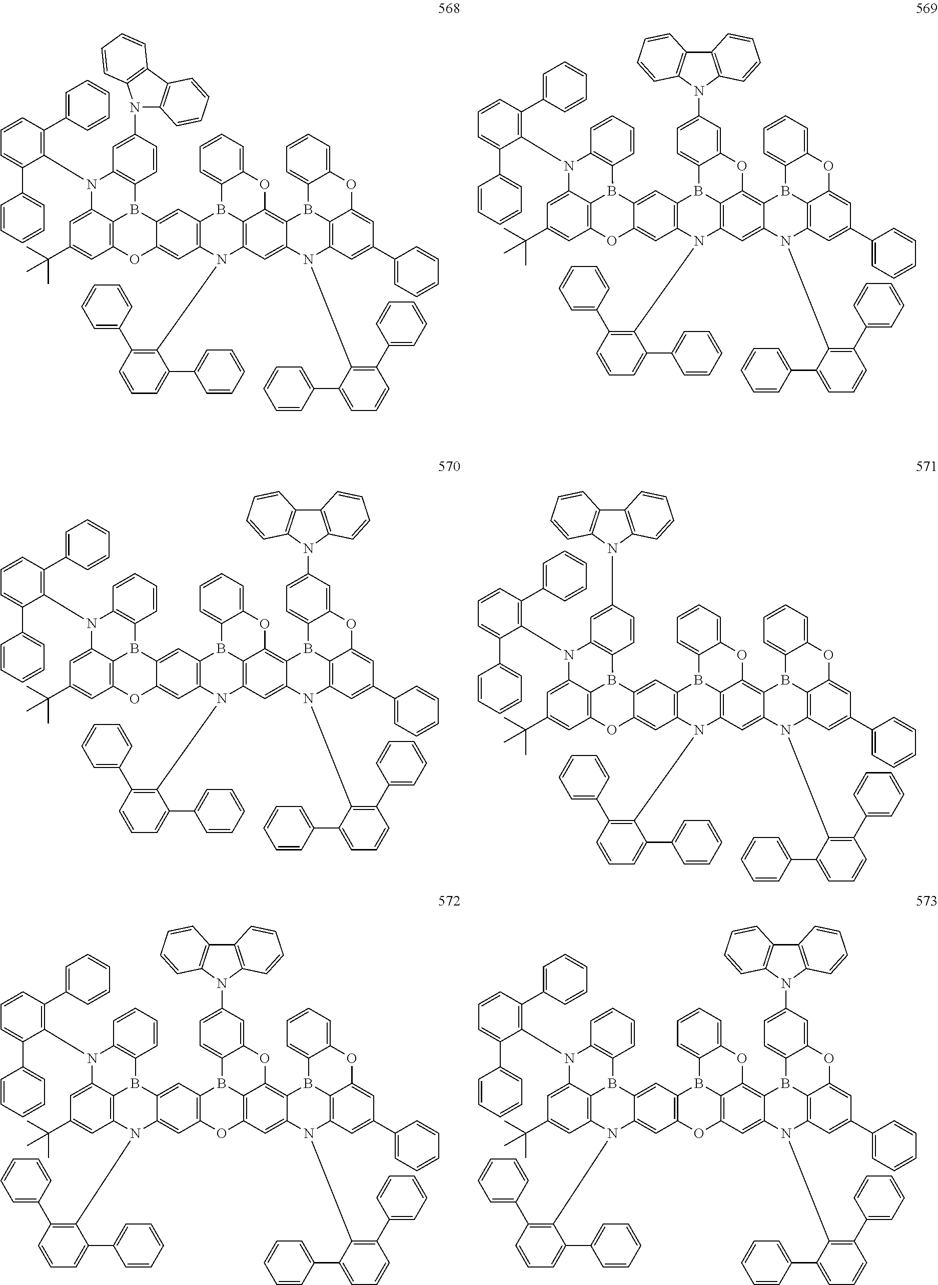

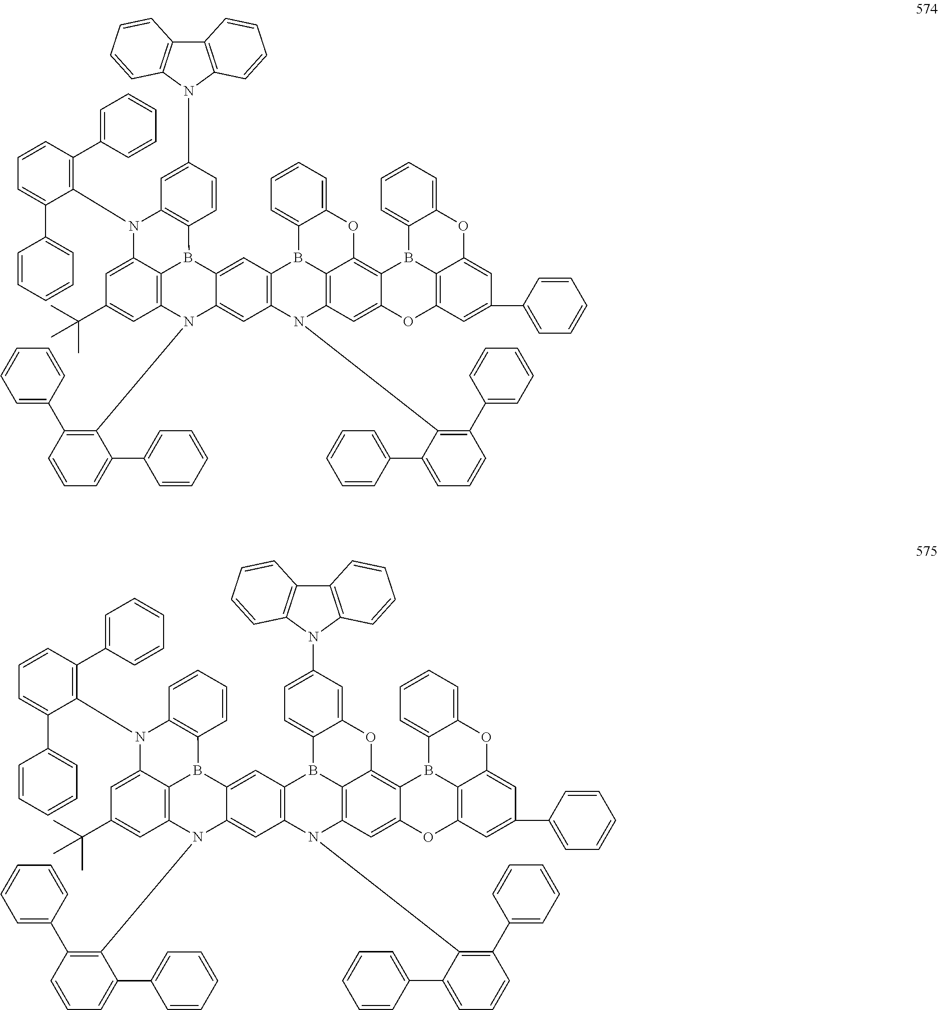 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1O2]

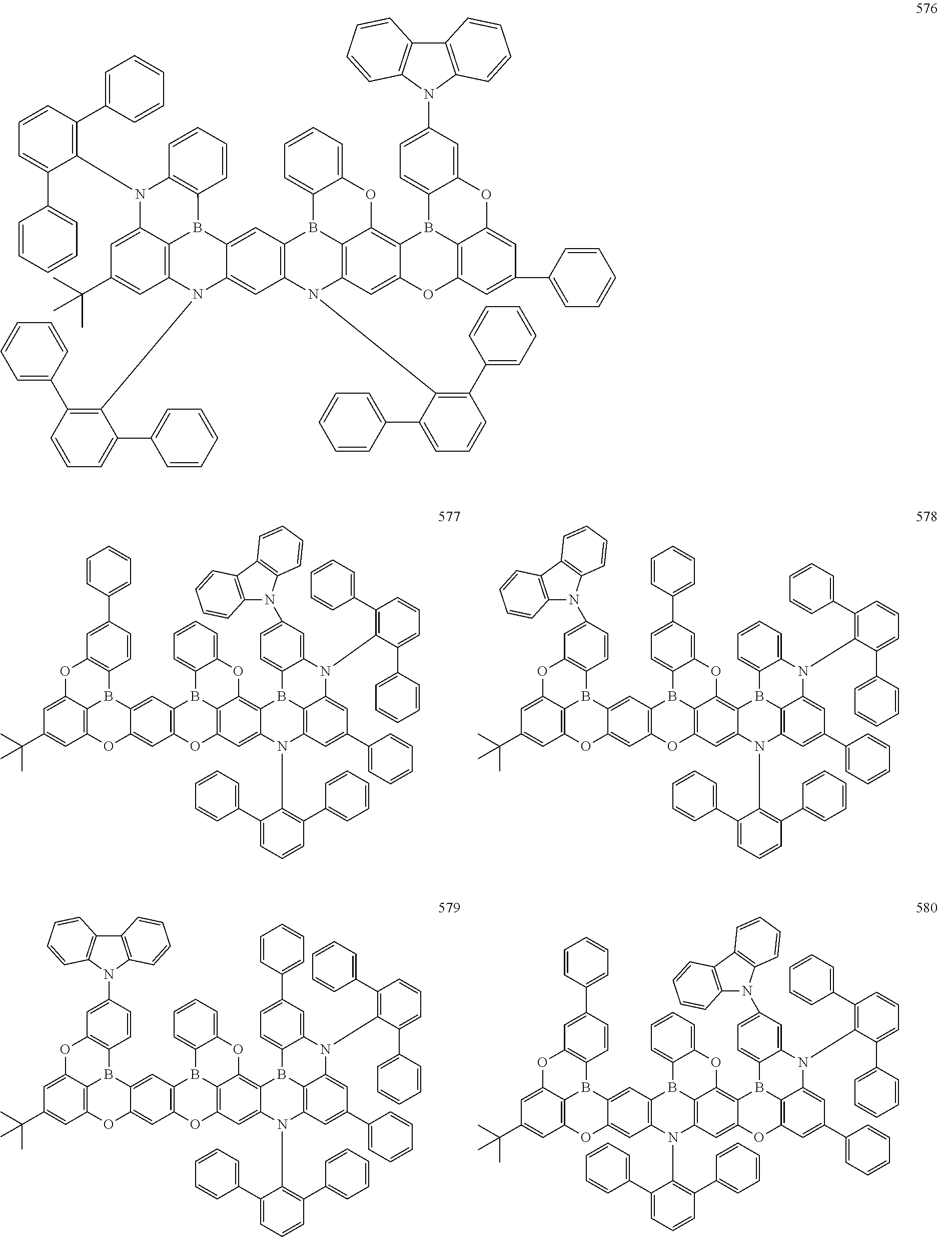

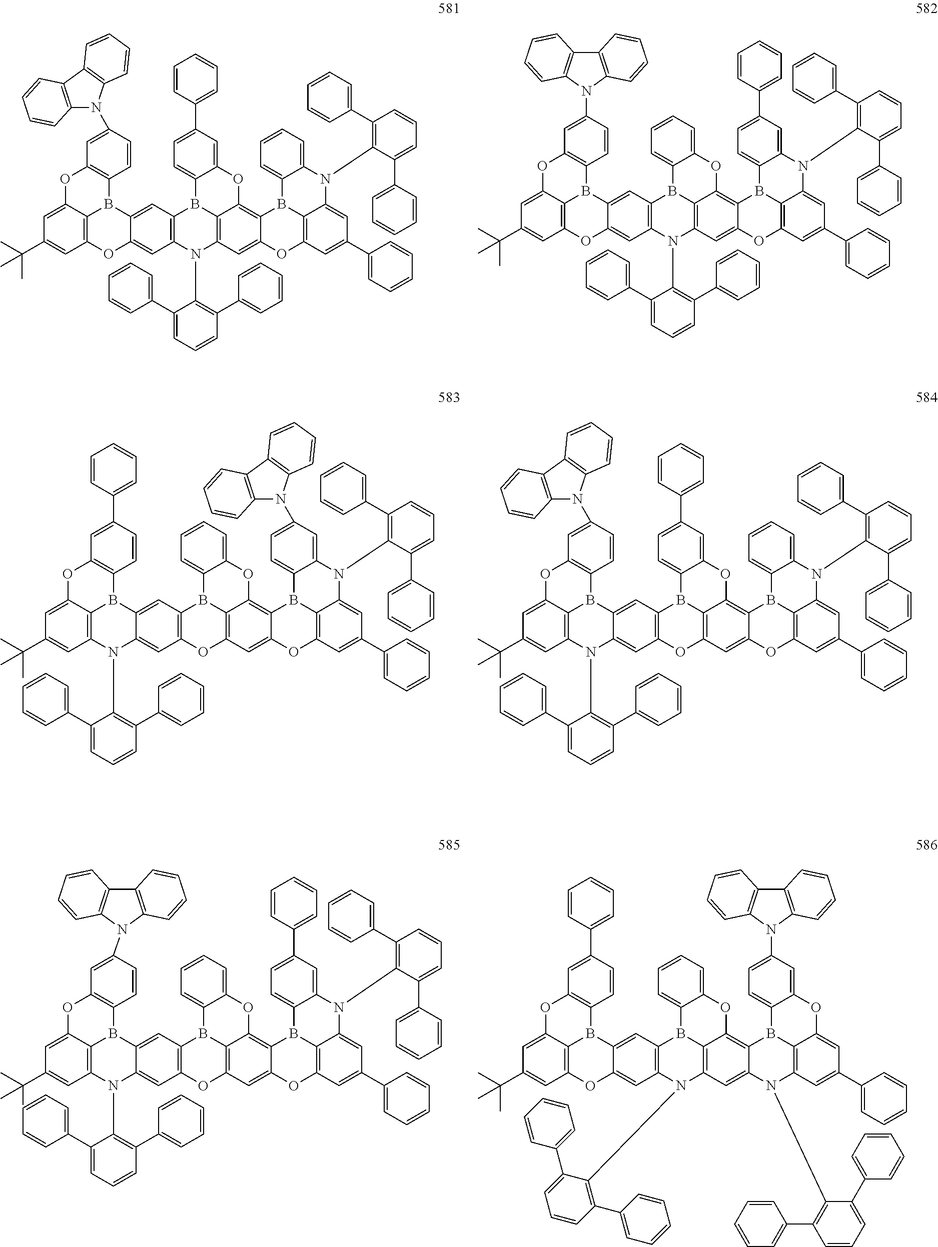

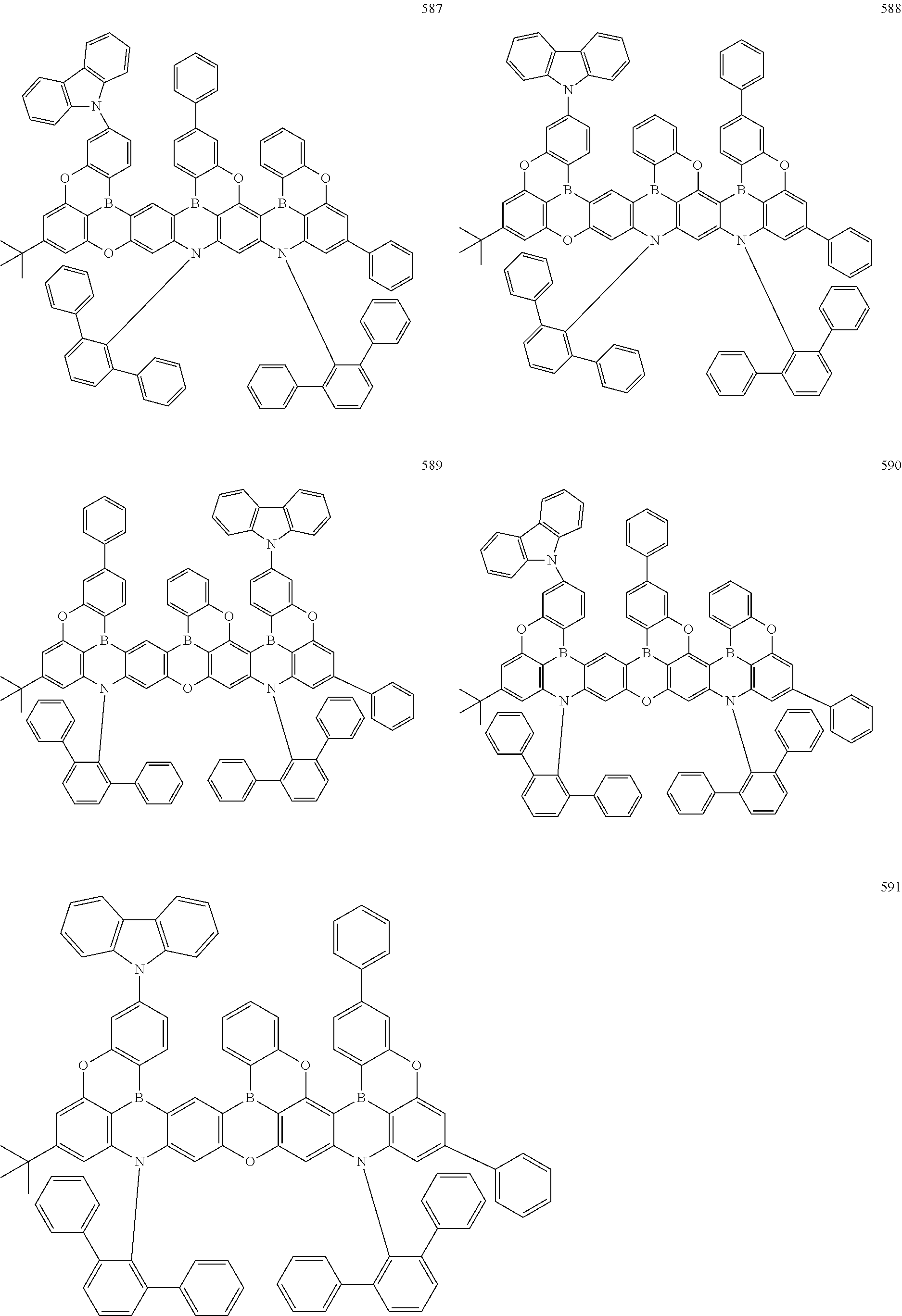

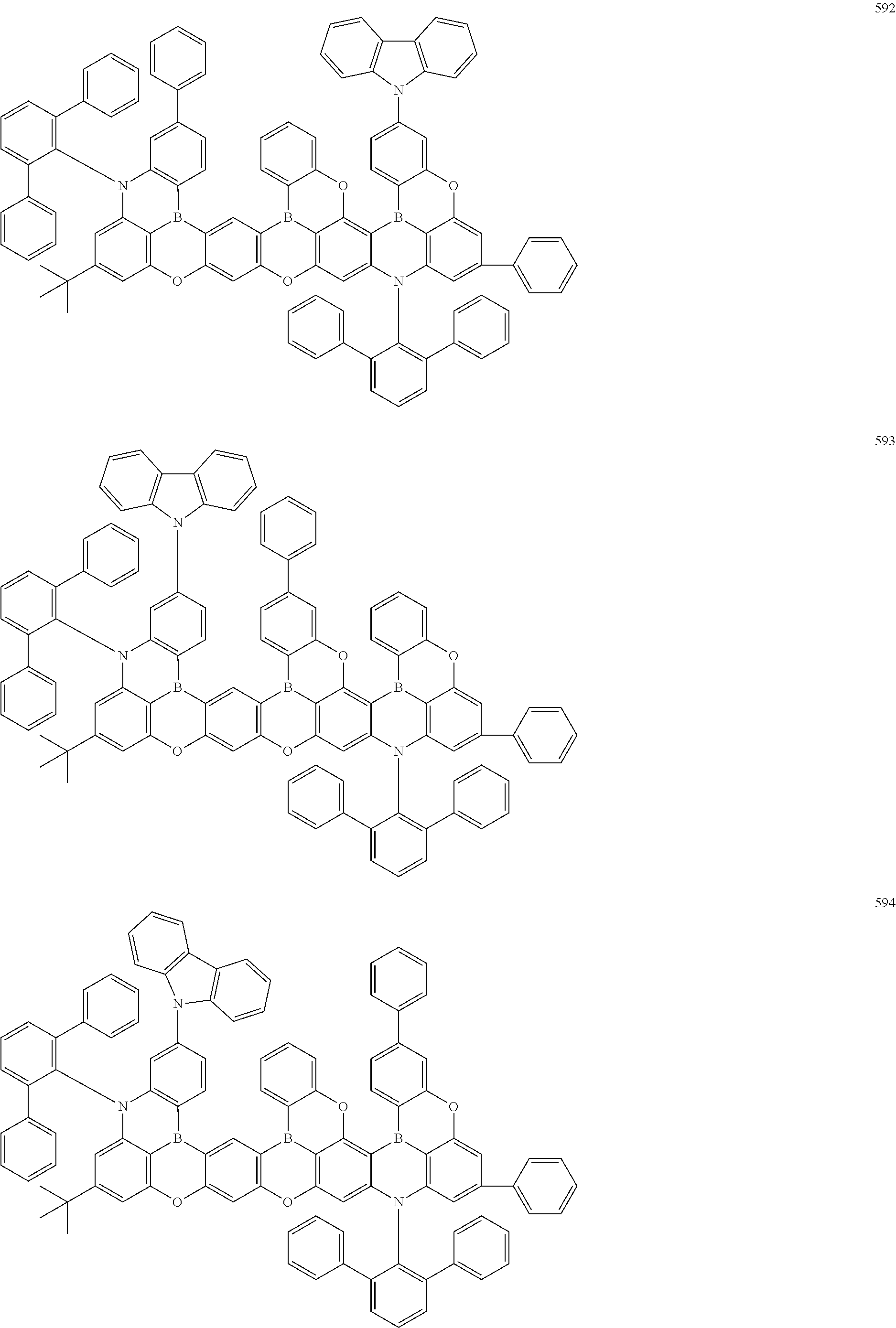

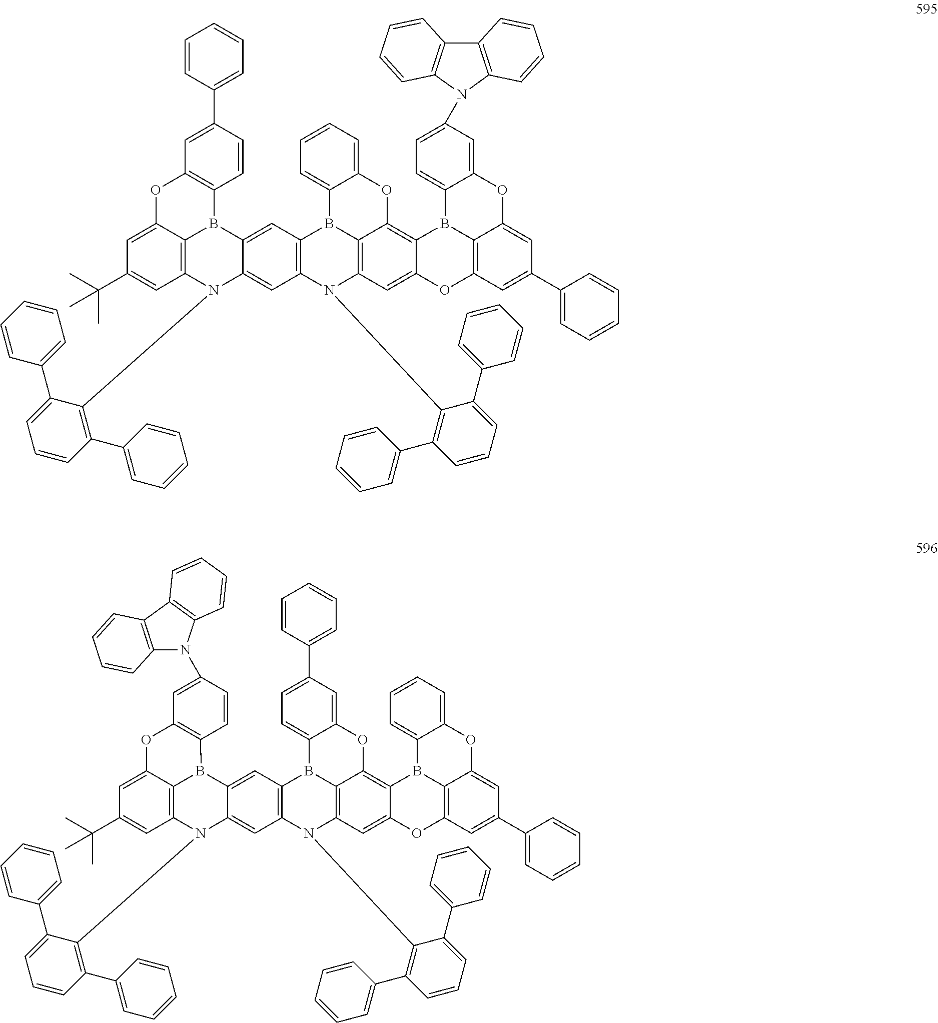 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1O2 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1O2]

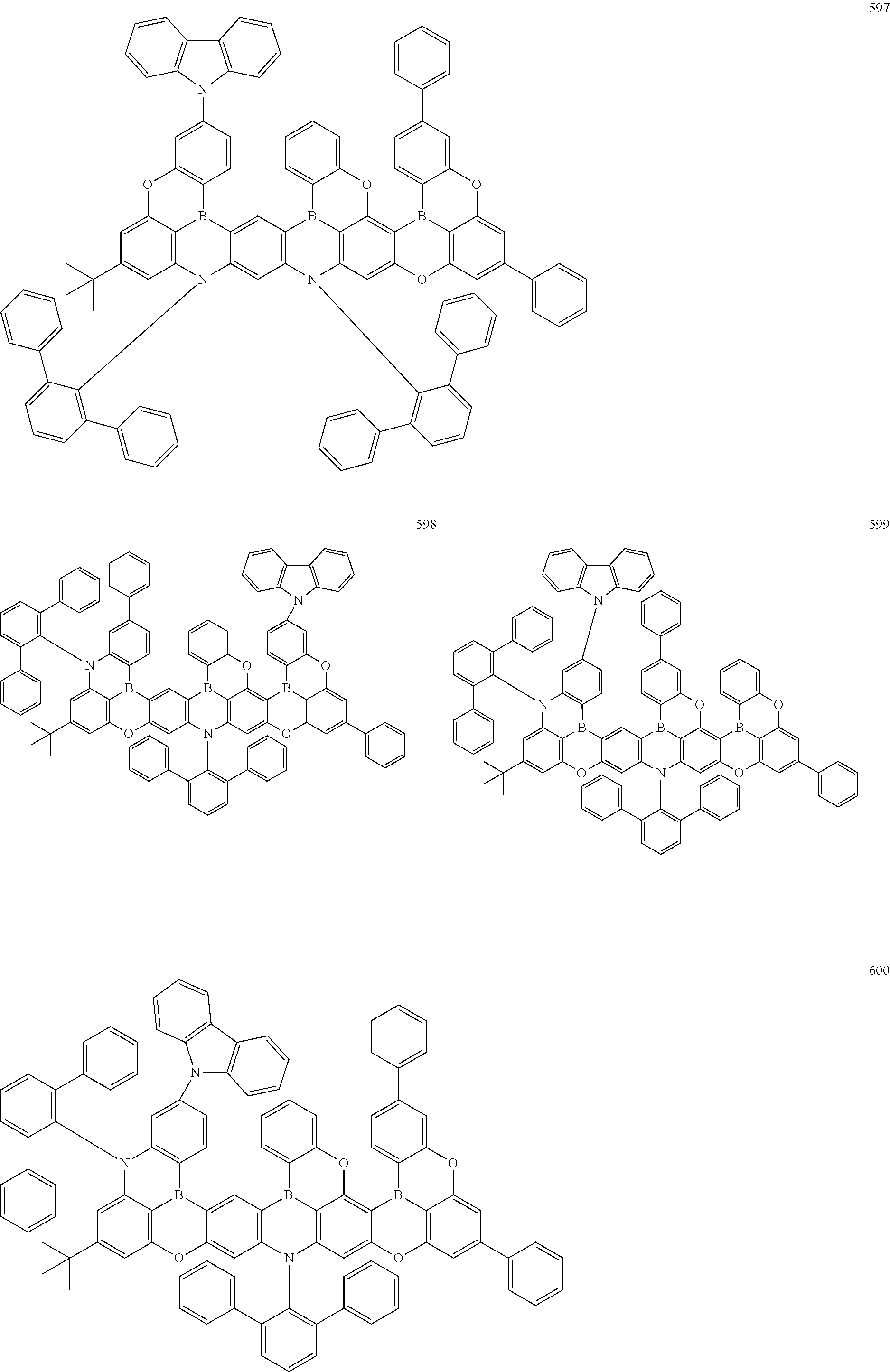

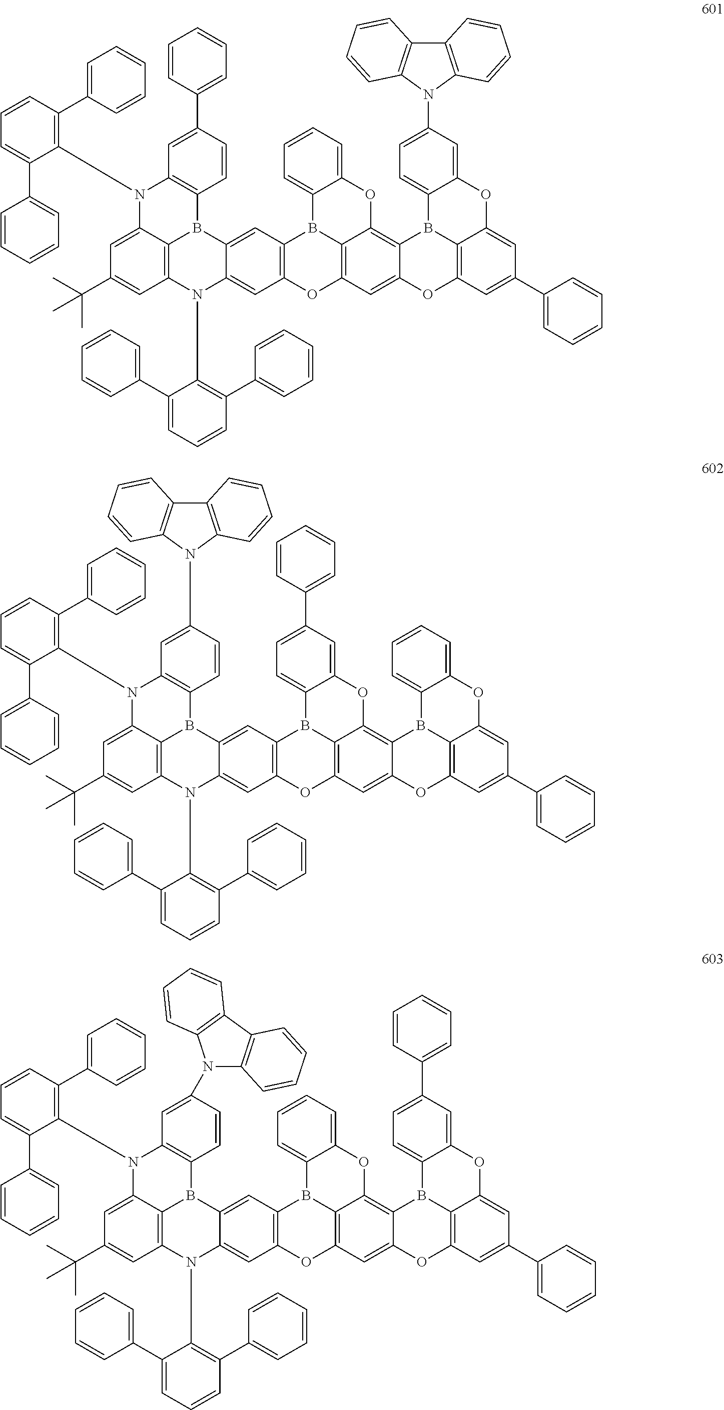

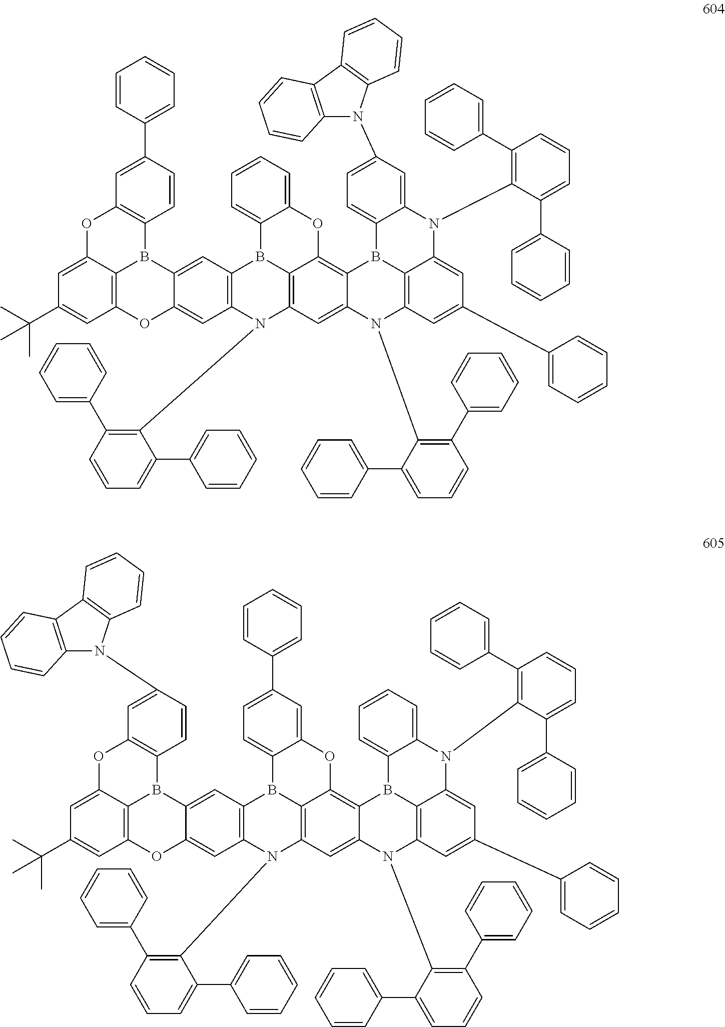 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccc(-n3c5ccccc5c5ccccc53)cc1O2)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1]

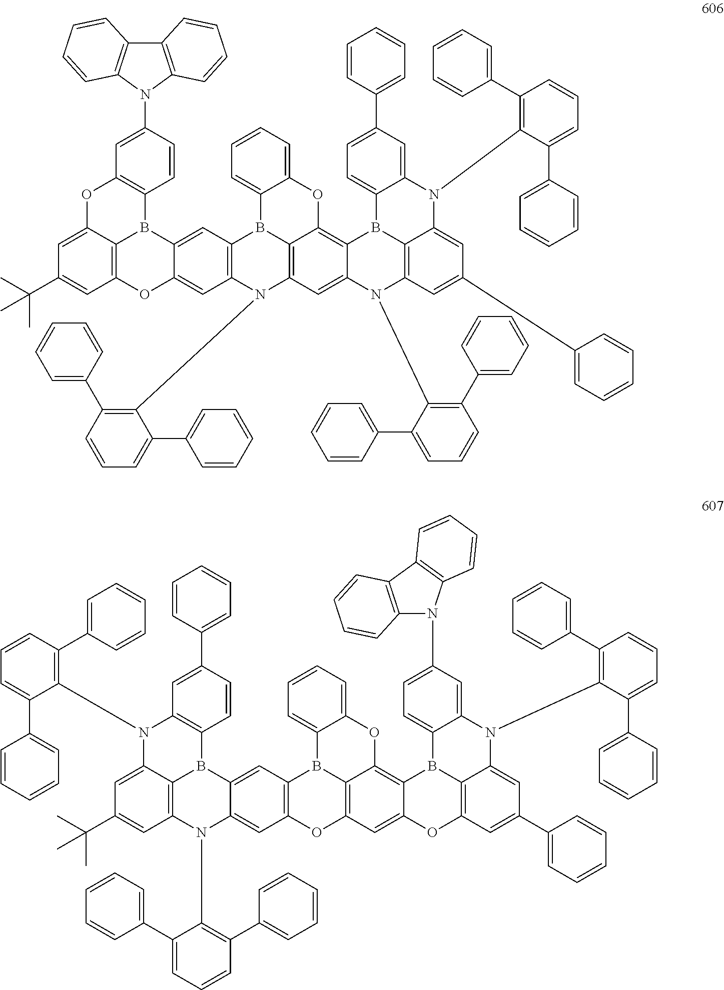 [SMILES: CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1N2c1c(-c2ccccc2)cccc1-c1ccccc1)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)O1)O4]

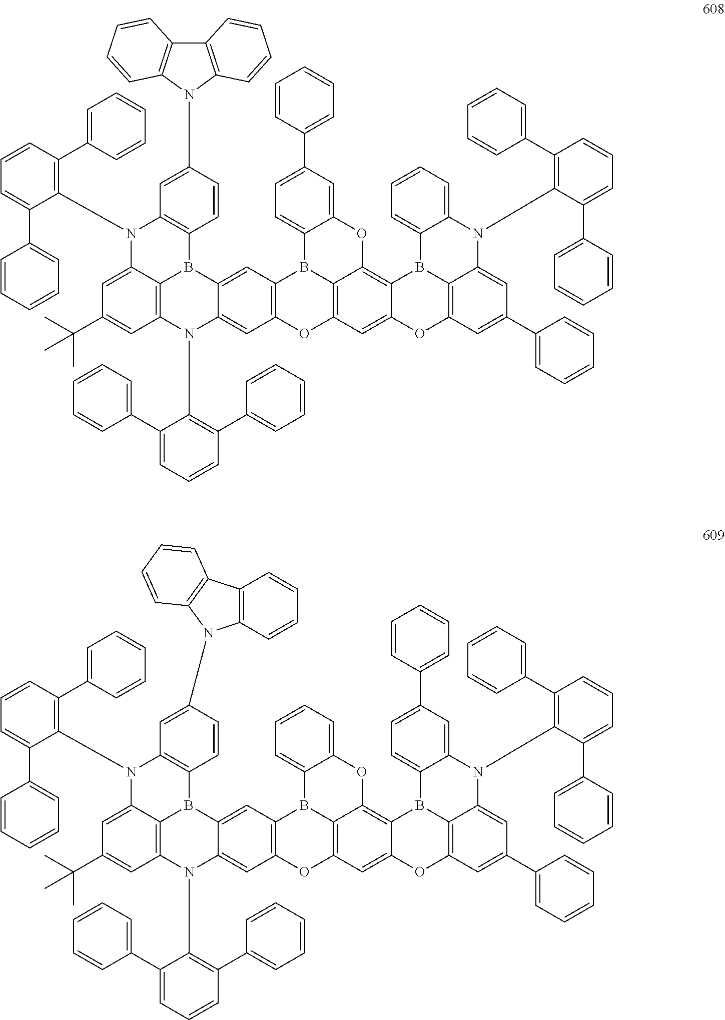 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)O1)O4]

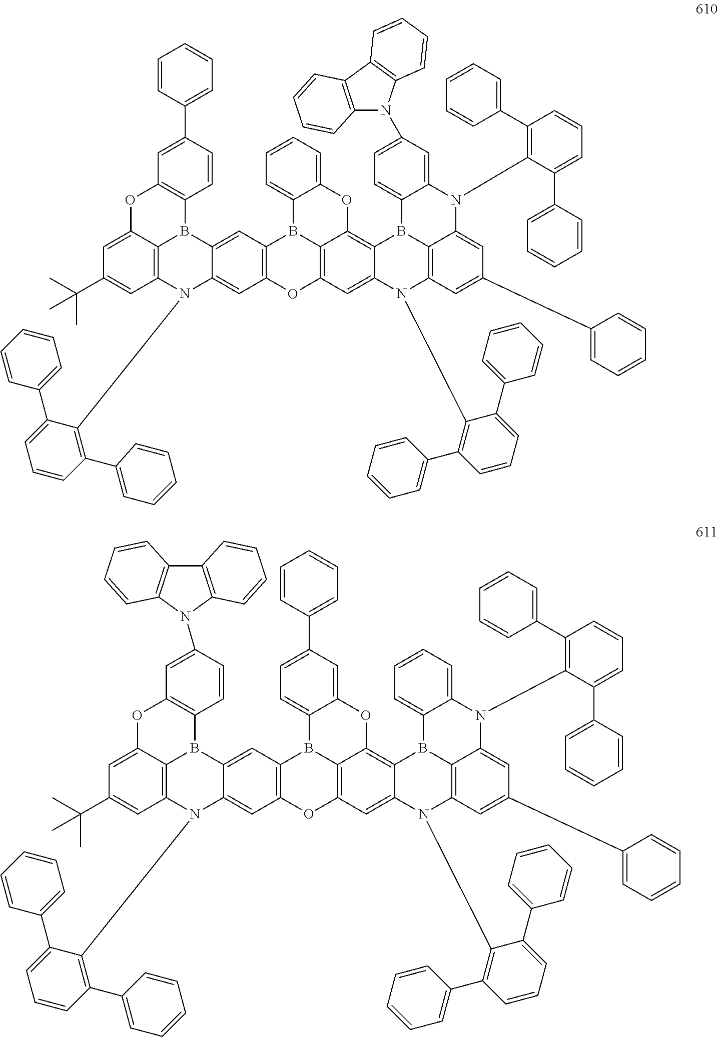

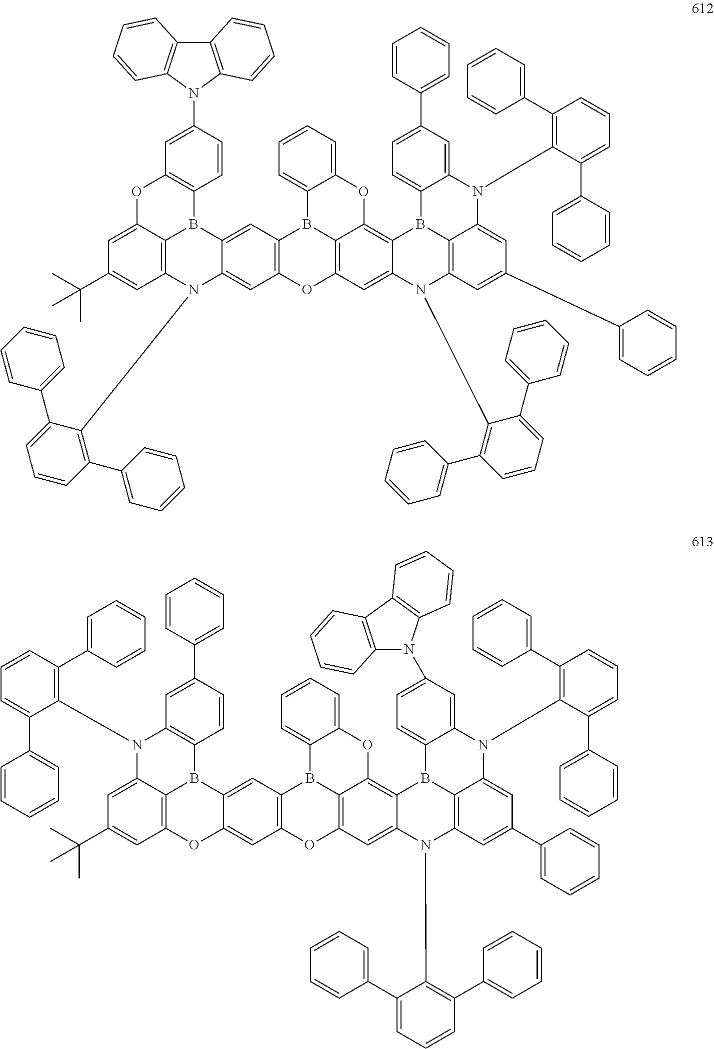 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccc(-n4c5ccccc5c5ccccc54)cc3N(c3c(-c4ccccc4)cccc3-c3ccccc3)c3cc(-c4ccccc4)cc(c31)N2c1c(-c2ccccc2)cccc1-c1ccccc1]

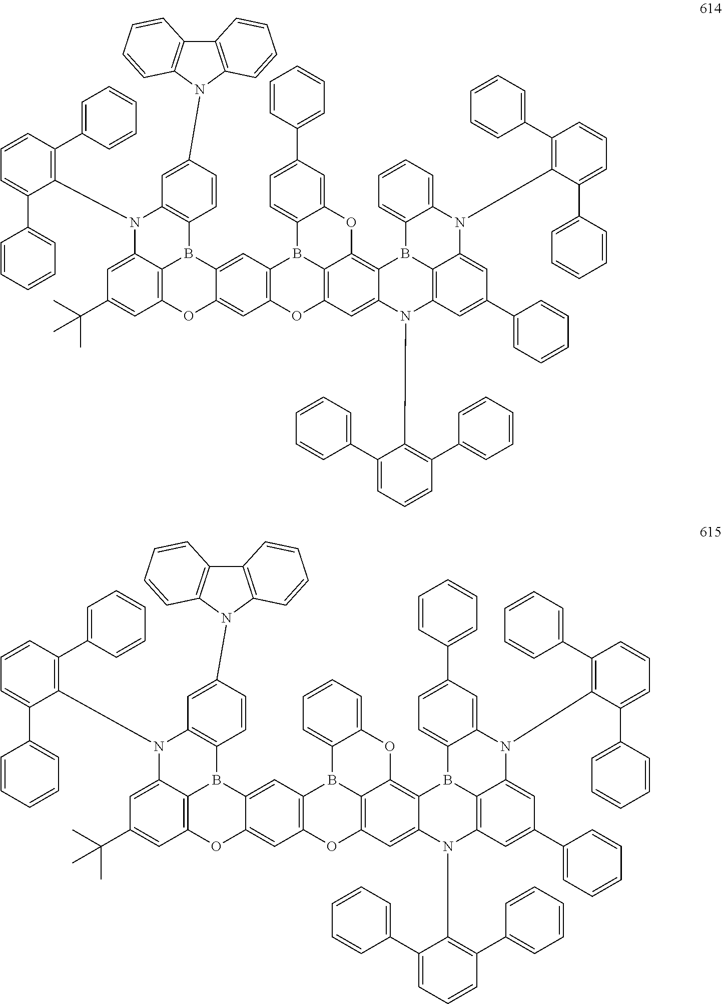 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(-c4ccccc4)cc(c31)N2c1c(-c2ccccc2)cccc1-c1ccccc1]

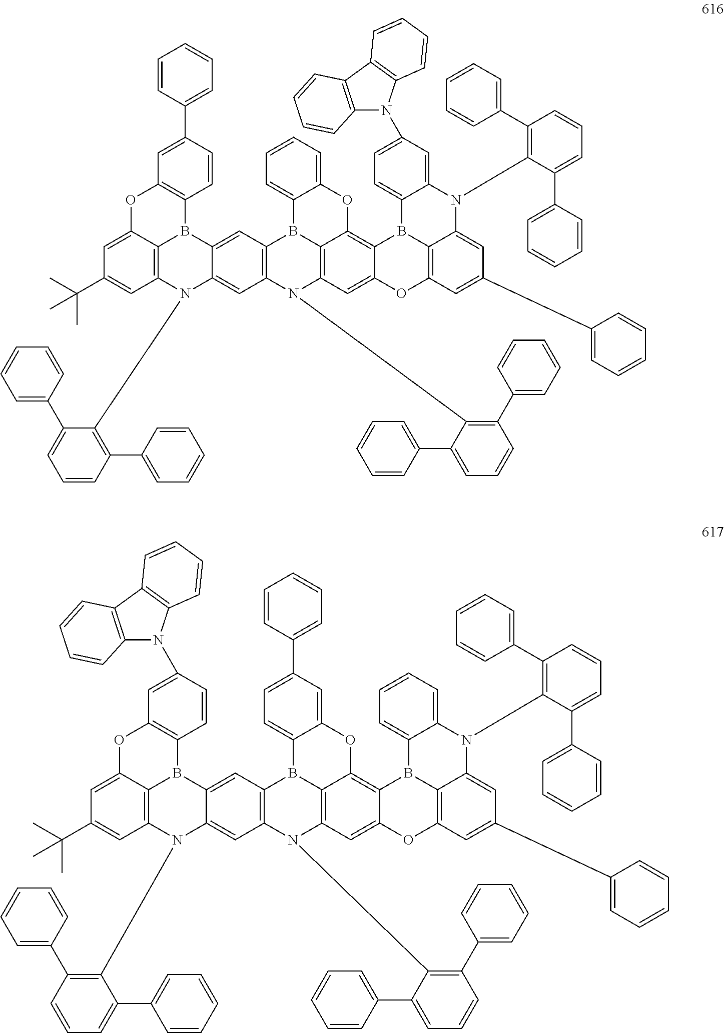 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1]

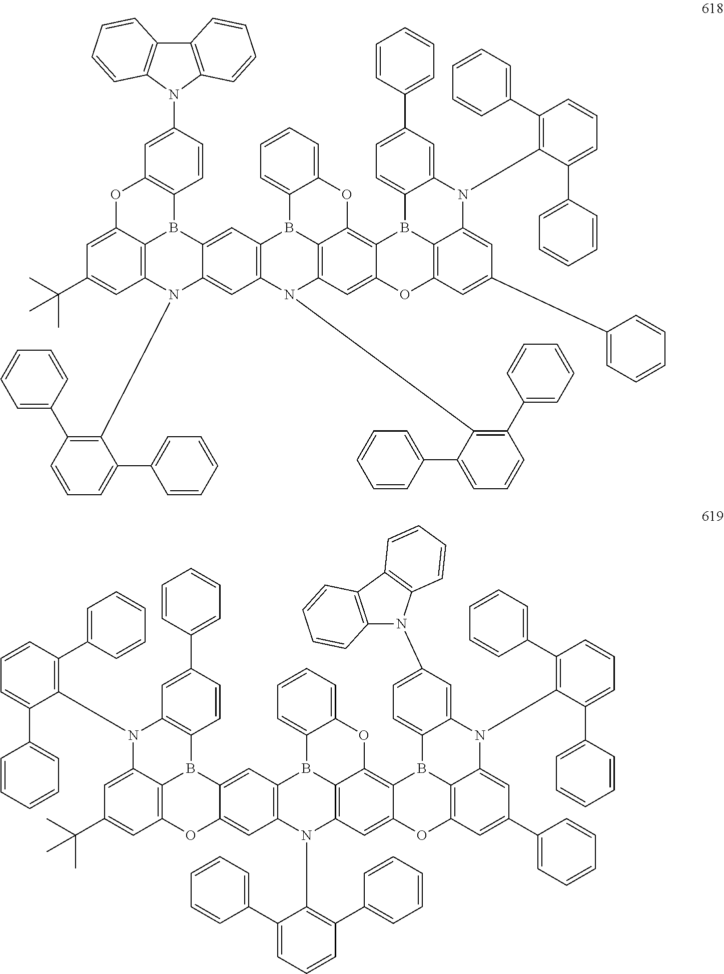

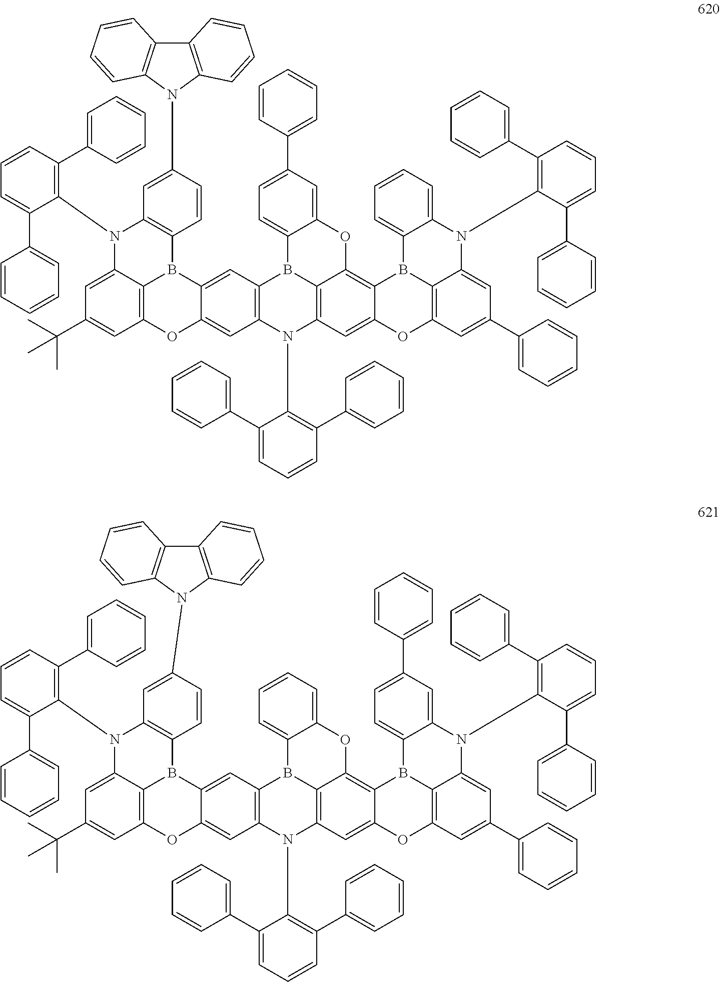 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3N(c3c(-c4ccccc4)cccc3-c3ccccc3)c3cc(-c4ccccc4)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3N(c3c(-c4ccccc4)cccc3-c3ccccc3)c3cc(-c4ccccc4)cc(c31)O2]

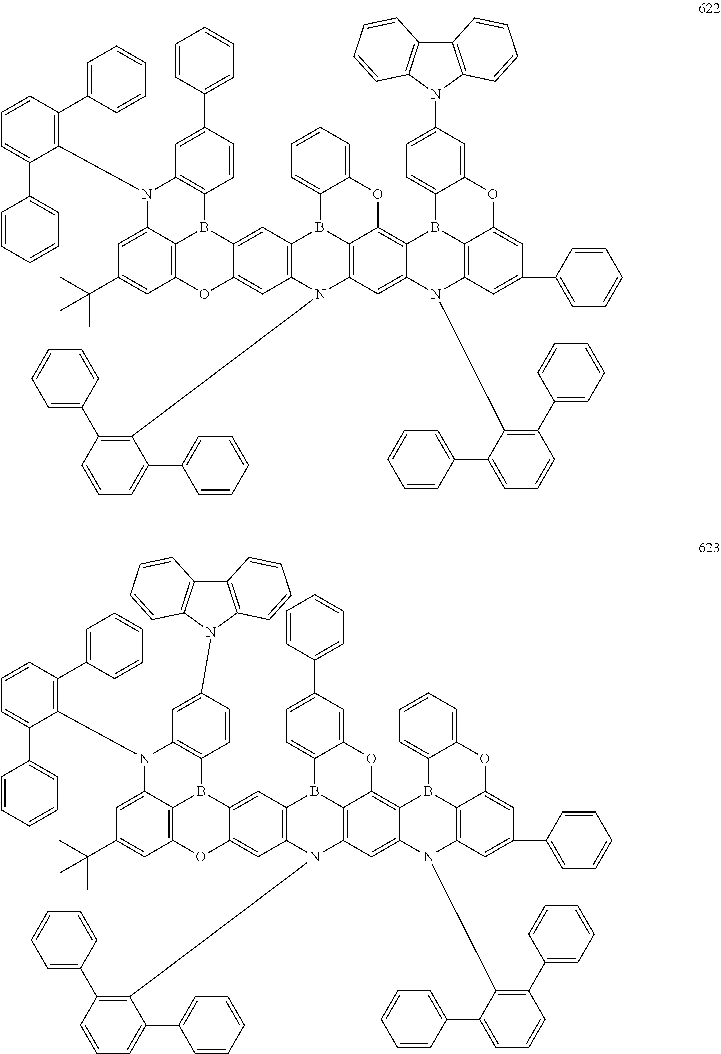 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3Oc3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3Oc3cc(-c4ccccc4)cc(c31)N2c1c(-c2ccccc2)cccc1-c1ccccc1]

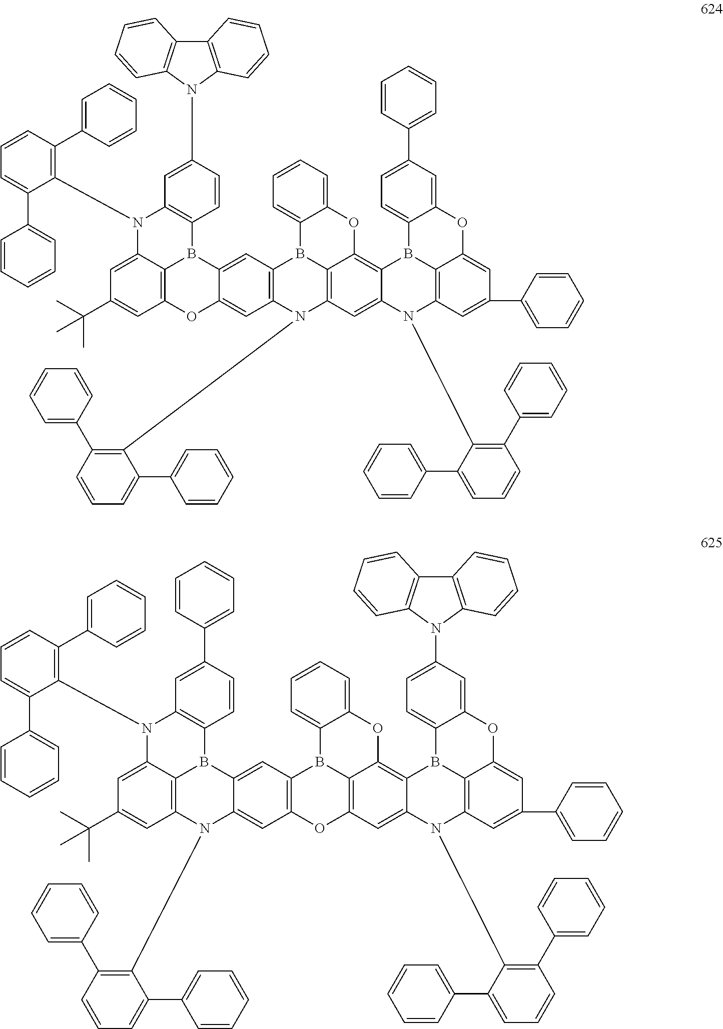 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3Oc3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1N2c1c(-c2ccccc2)cccc1-c1ccccc1)B1c2ccccc2Oc2c1c(cc1c2B2c3ccc(-n5c6ccccc6c6ccccc65)cc3Oc3cc(-c5ccccc5)cc(c32)N1c1c(-c2ccccc2)cccc1-c1ccccc1)O4]

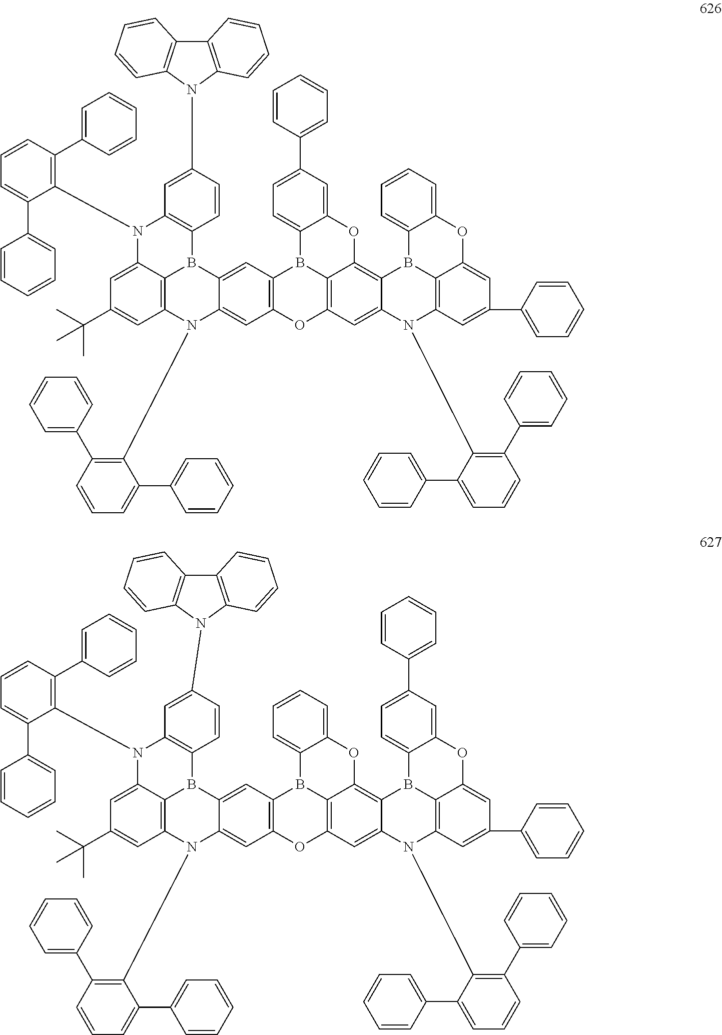 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccc(-c3ccccc3)cc2Oc2c1c(cc1c2B2c3ccccc3Oc3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c1c(cc1c2B2c3ccc(-c5ccccc5)cc3Oc3cc(-c5ccccc5)cc(c32)N1c1c(-c2ccccc2)cccc1-c1ccccc1)O4]

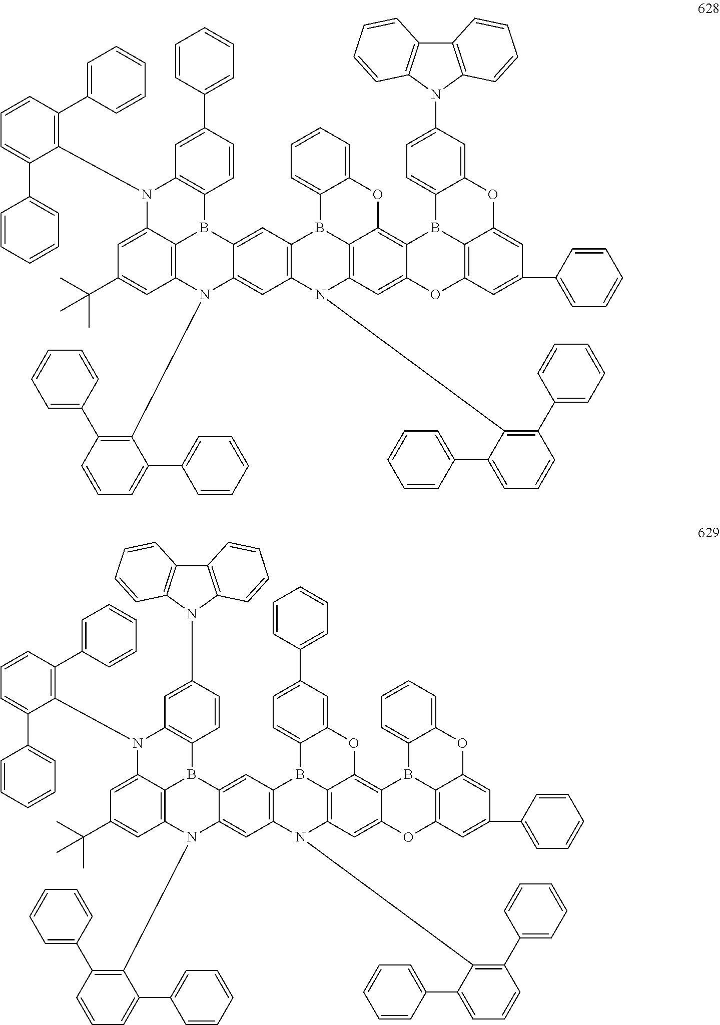 [SMILES: CC(C)(C)c1cc2c3c(c1)N(c1c(-c4ccccc4)cccc1-c1ccccc1)c1cc4c(cc1B3c1ccc(-c3ccccc3)cc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1O2 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1O2]

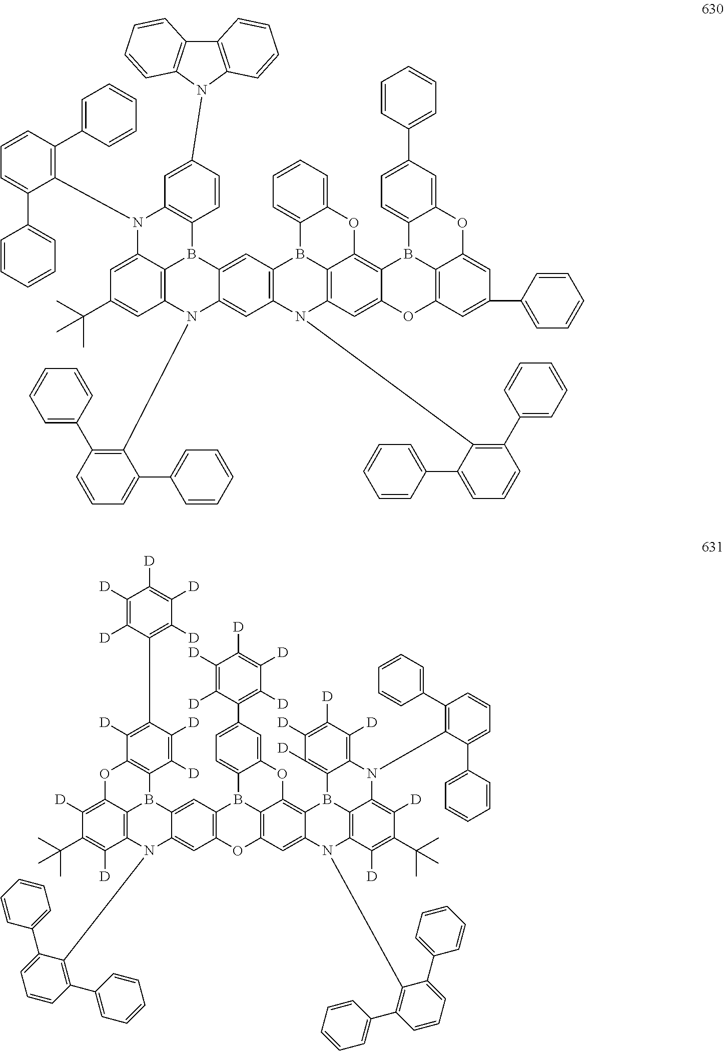

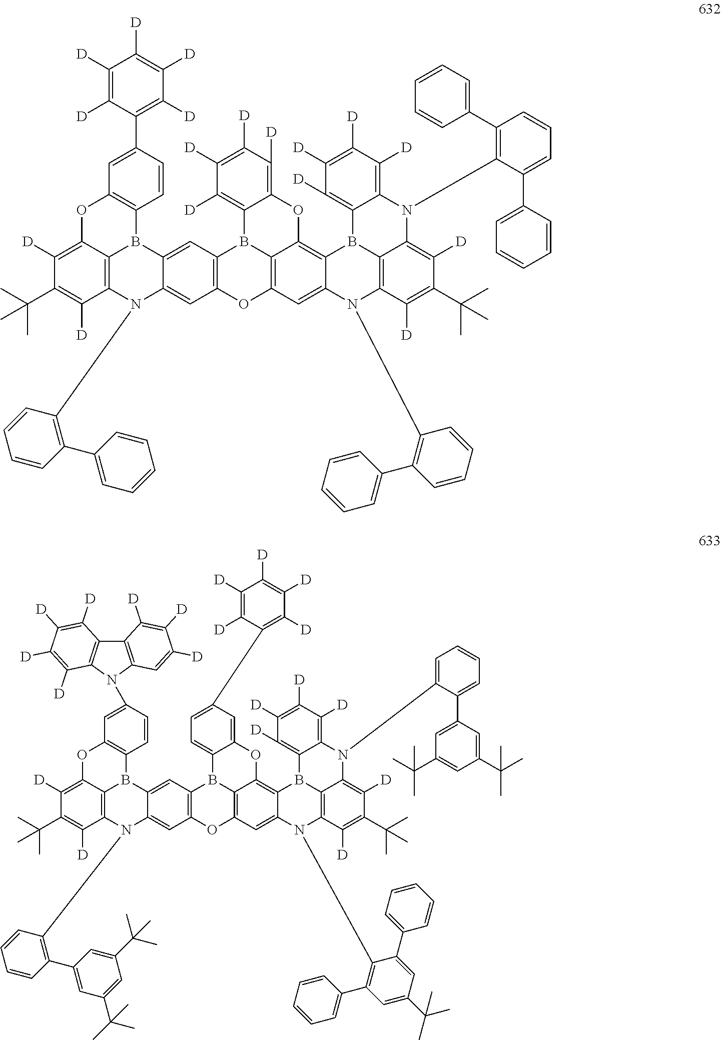

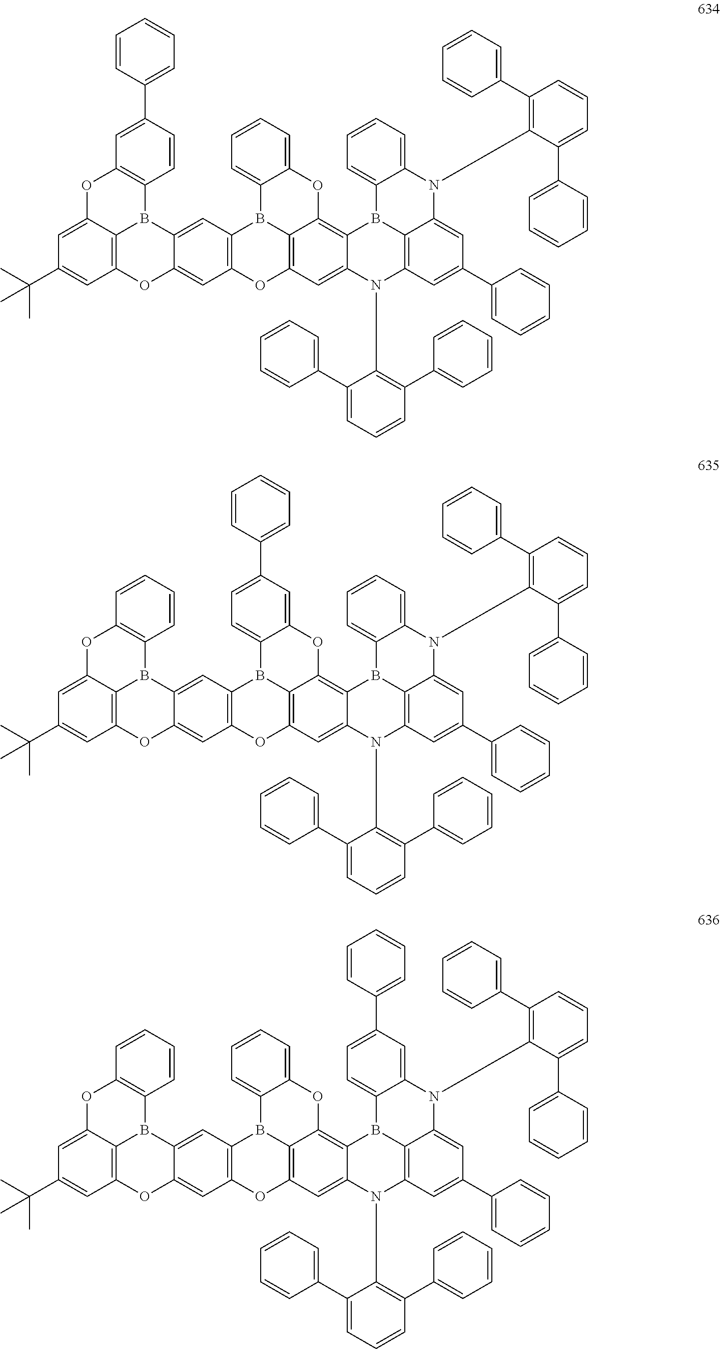

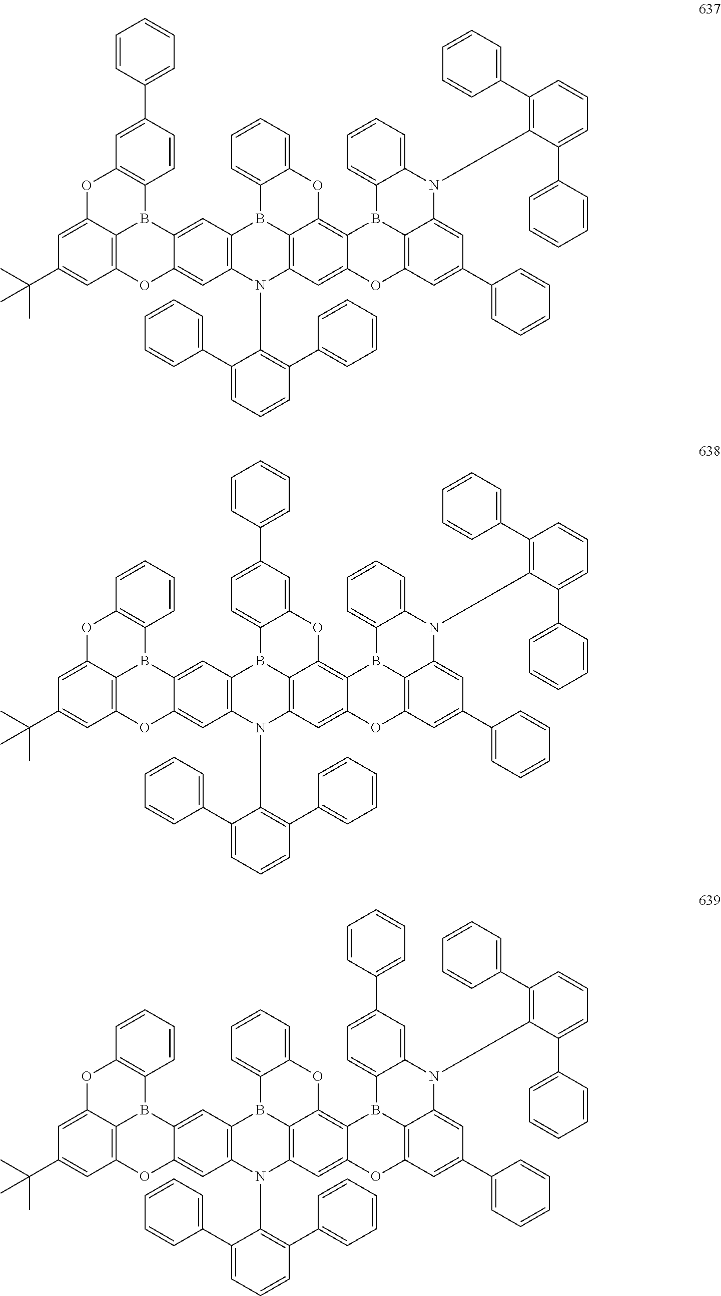

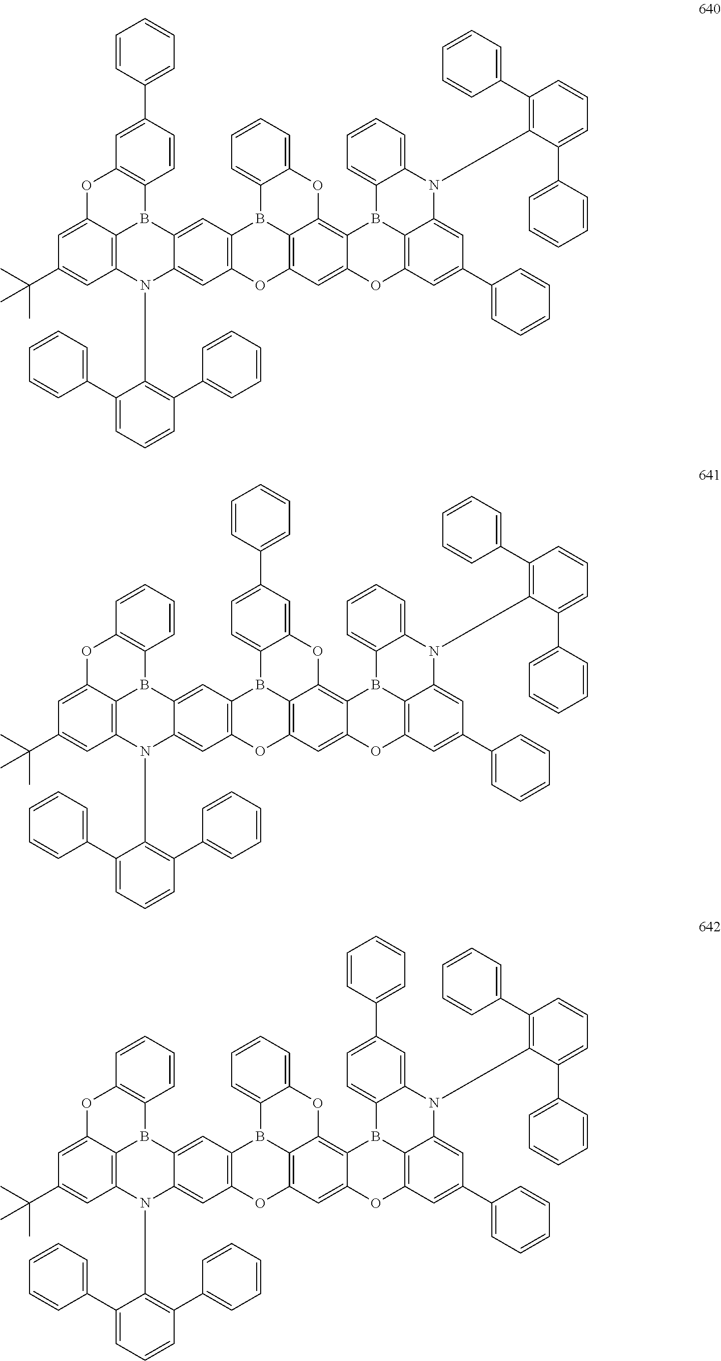

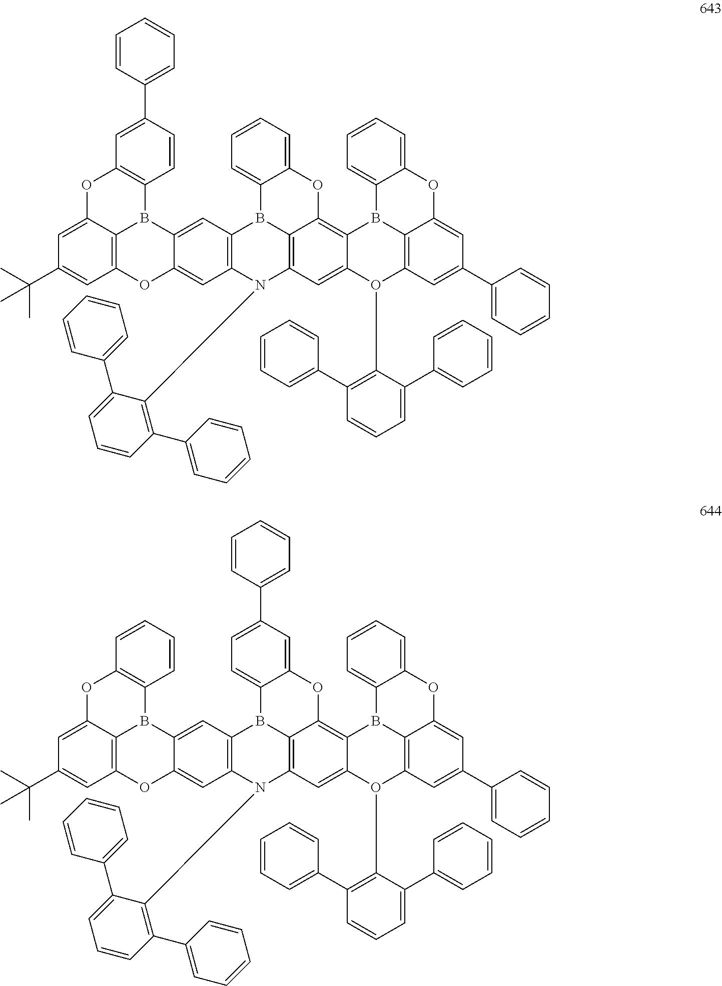

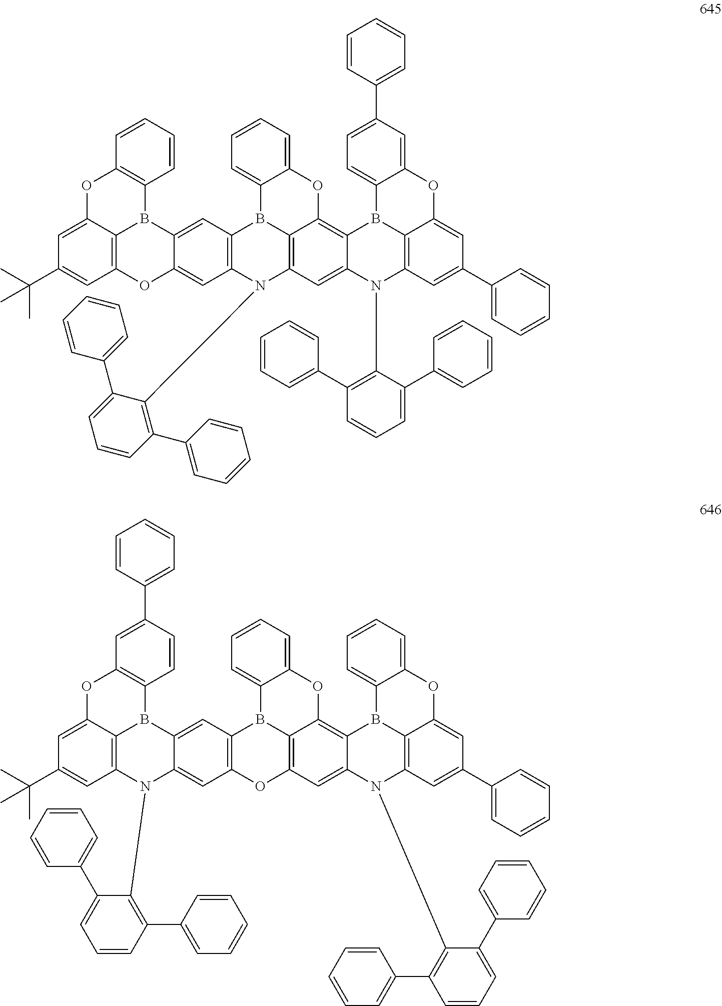 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3Oc3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccccc3Oc3cc(-c5ccccc5)cc(c32)N1c1c(-c2ccccc2)cccc1-c1ccccc1)O4]

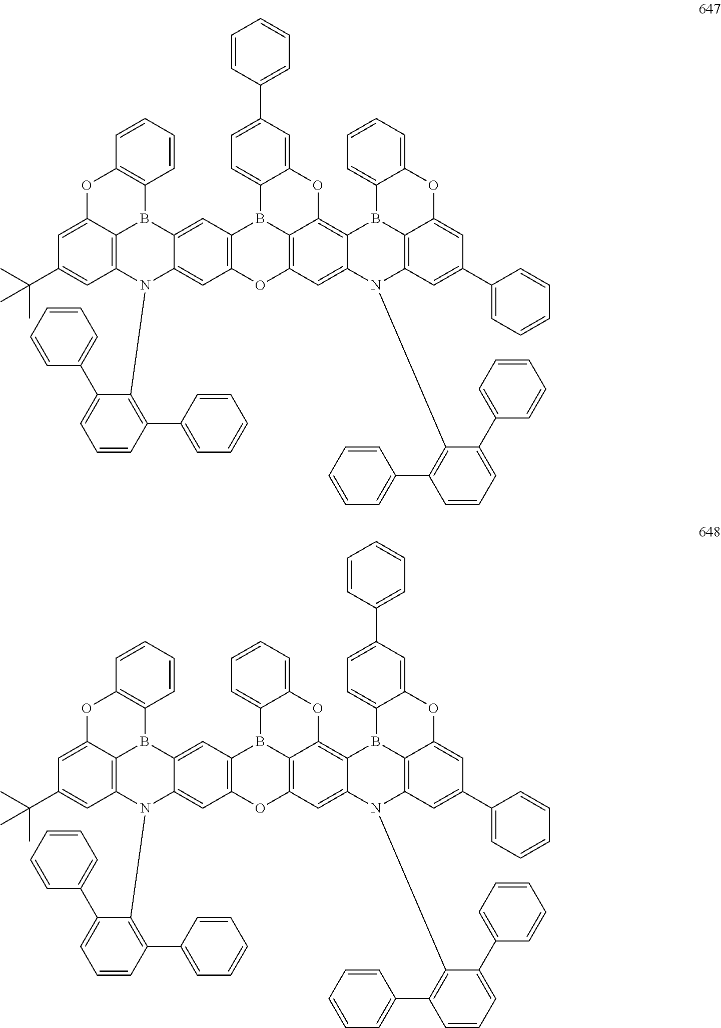

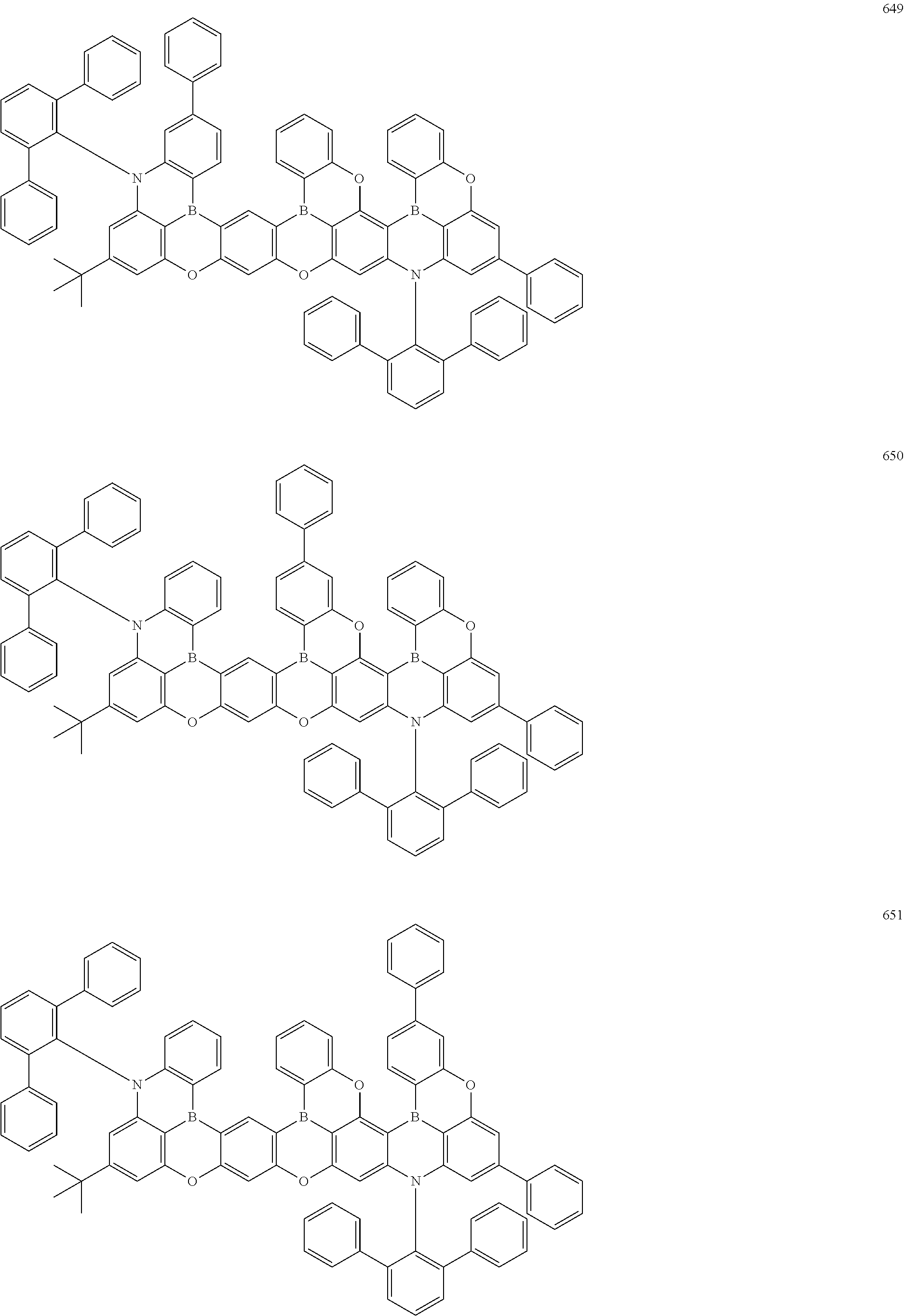

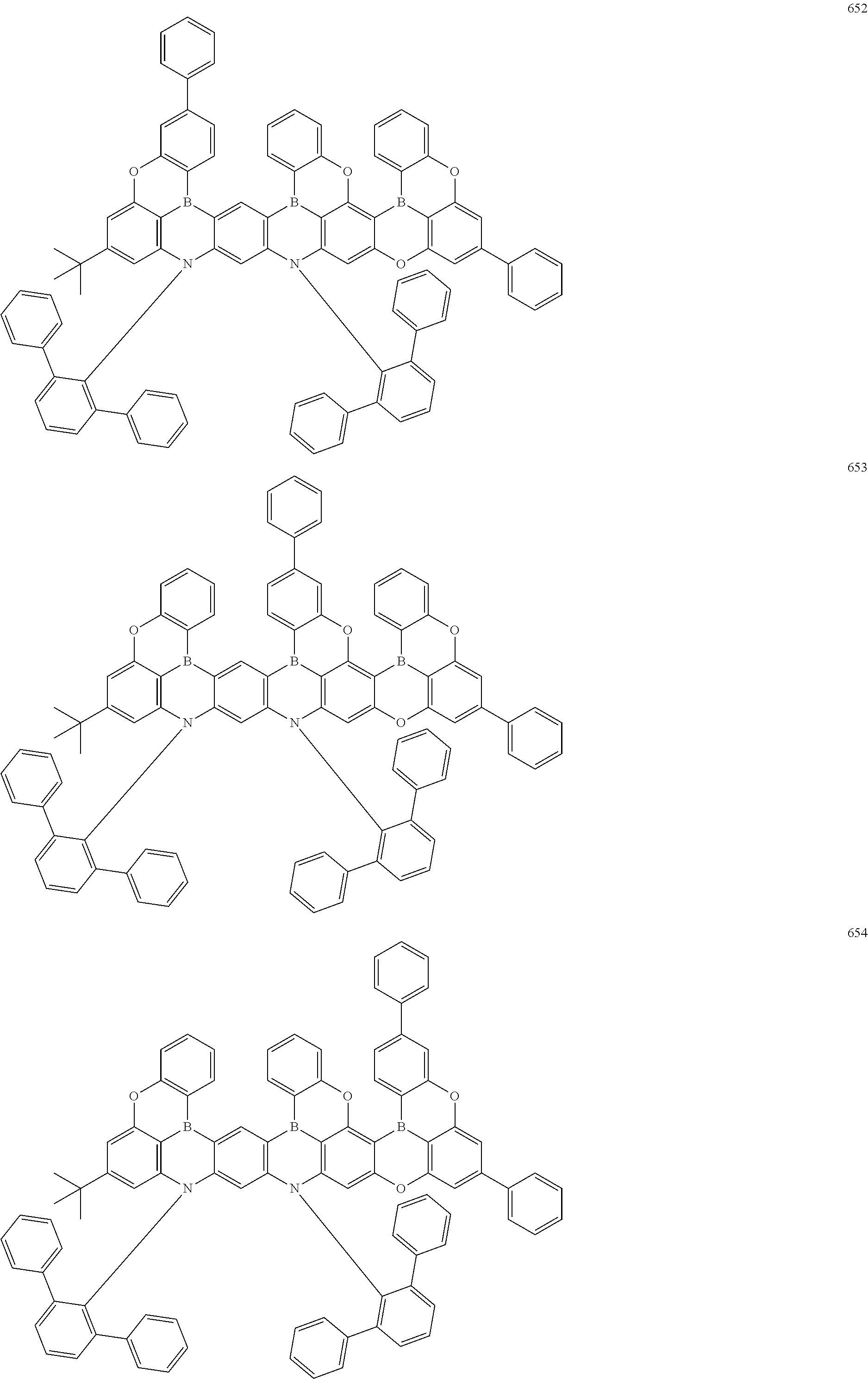

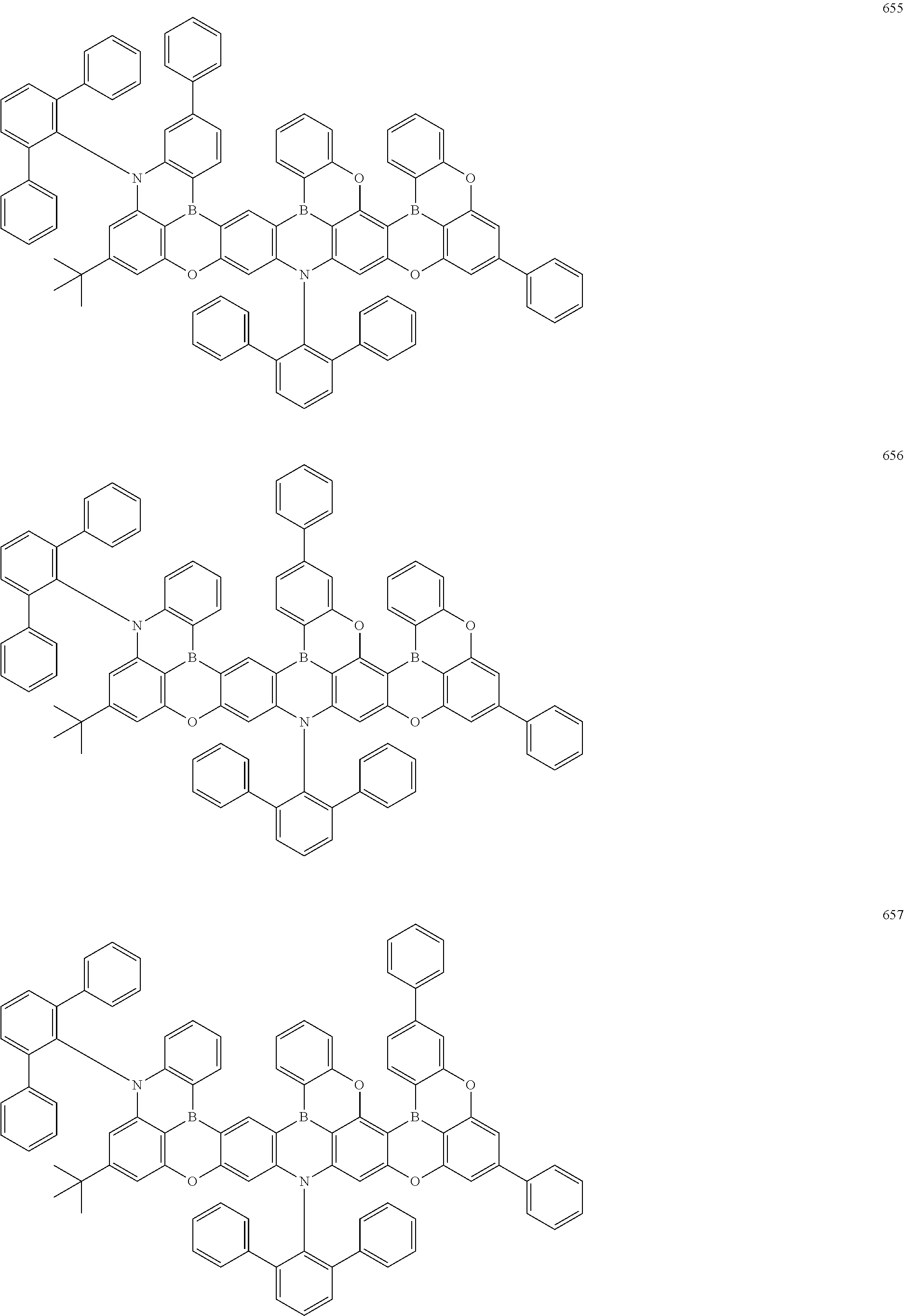

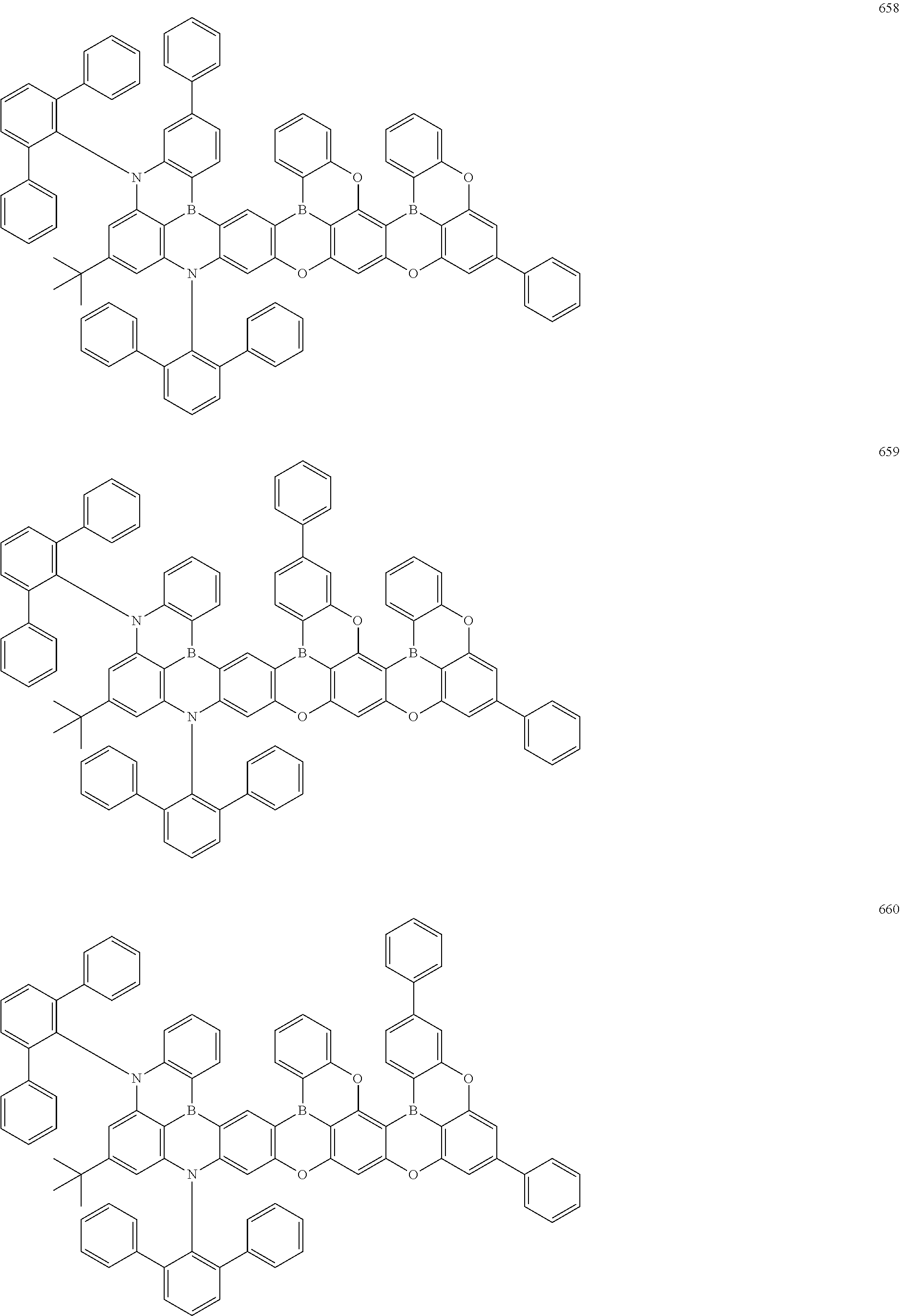

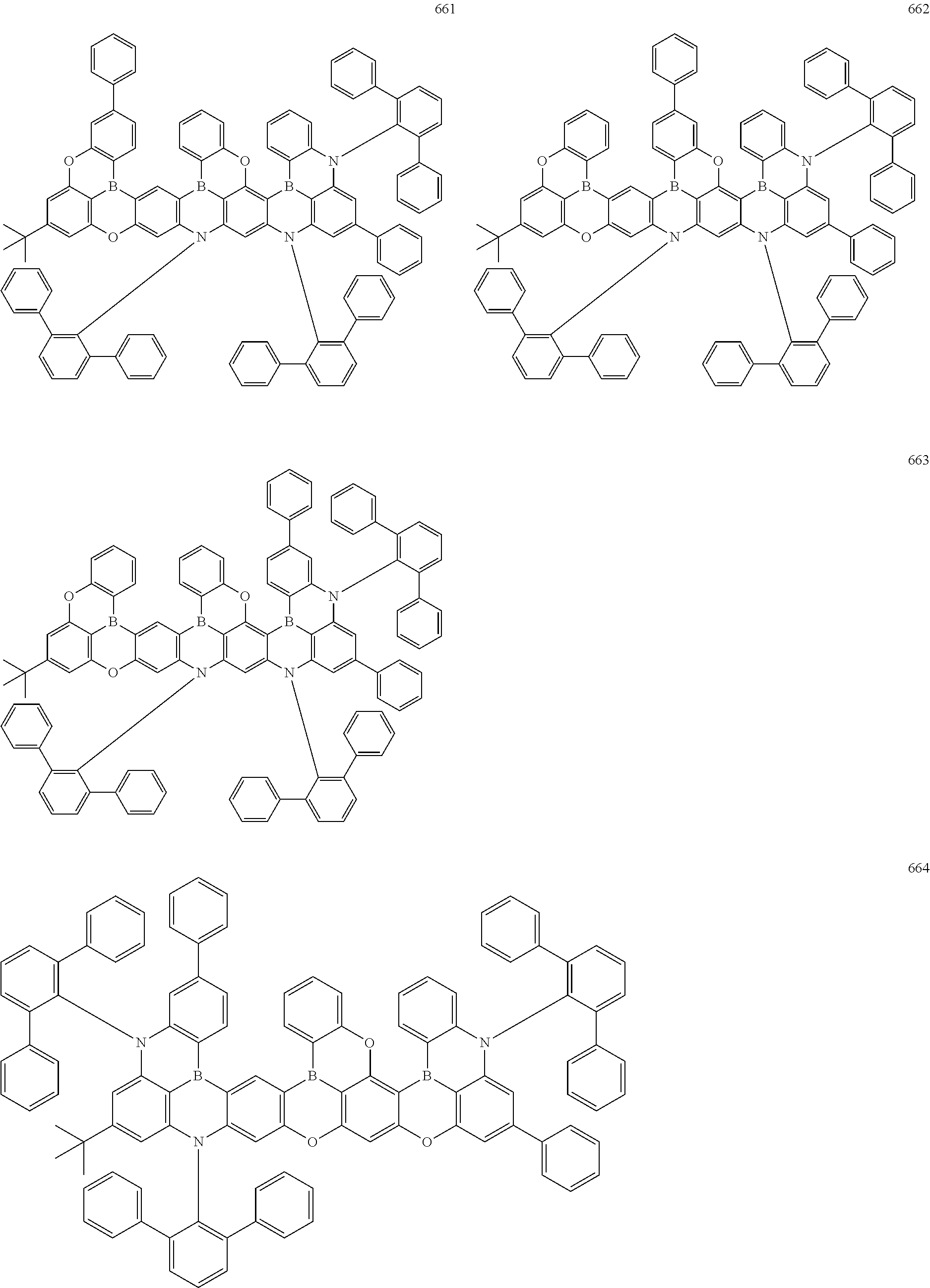

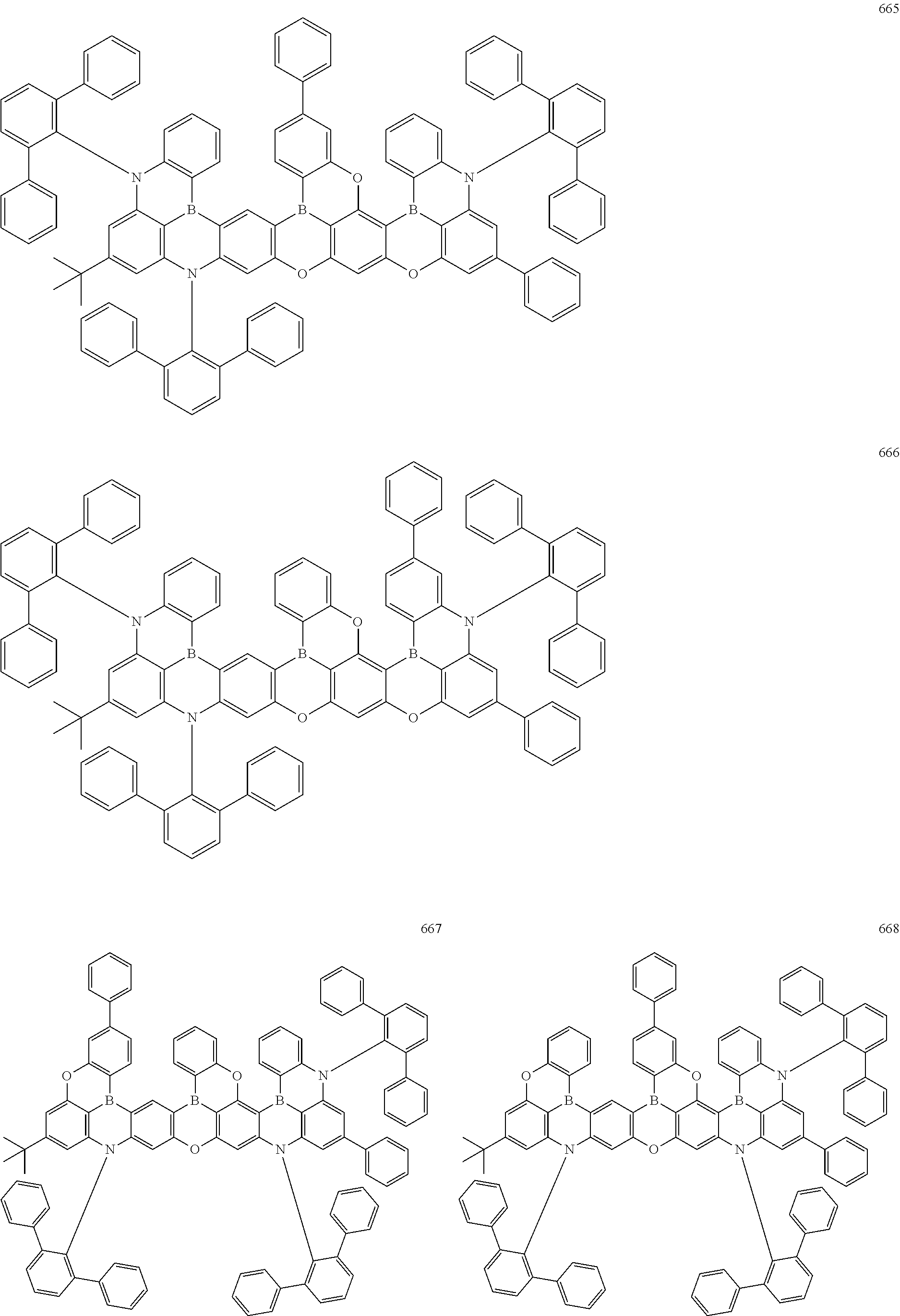

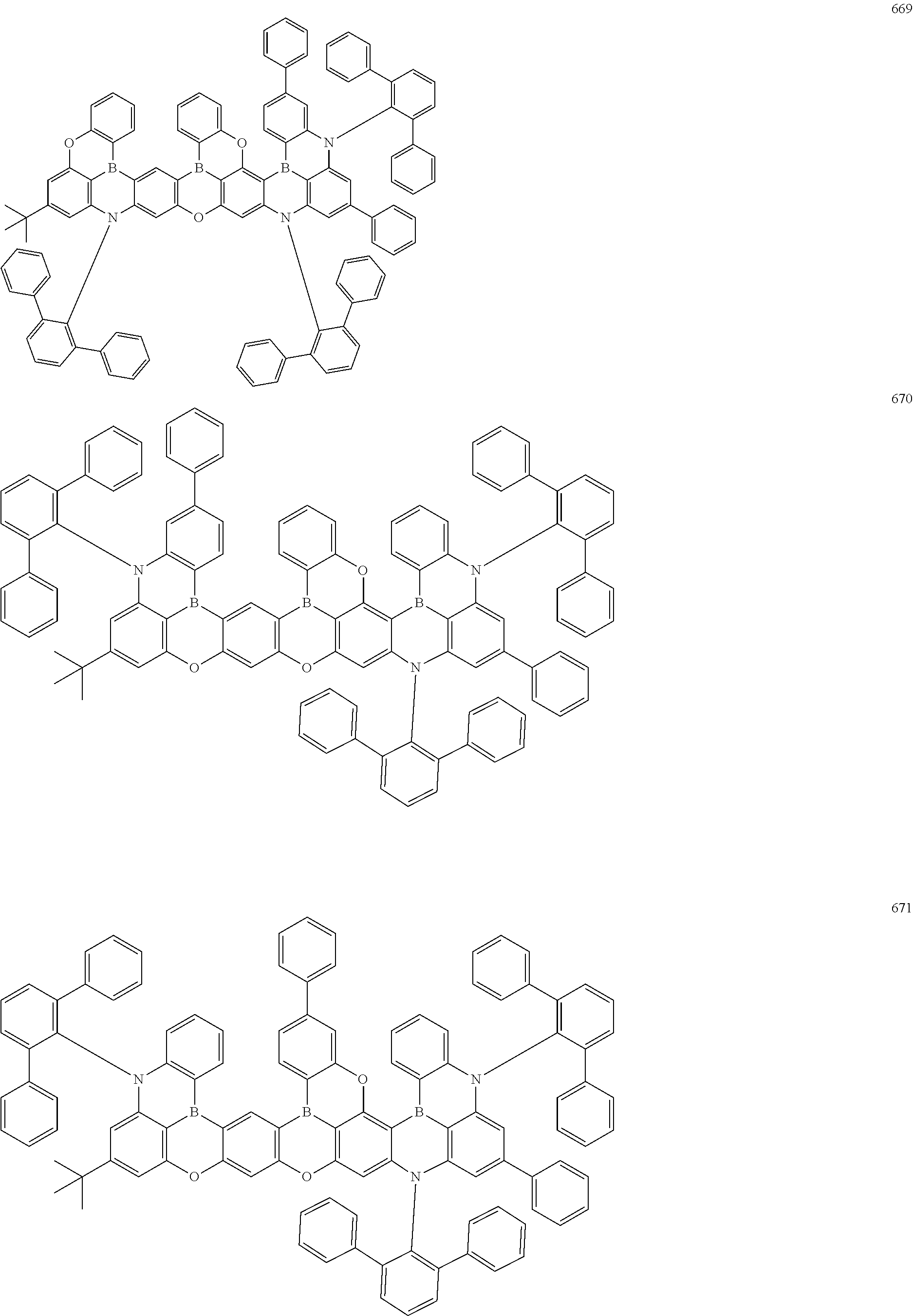

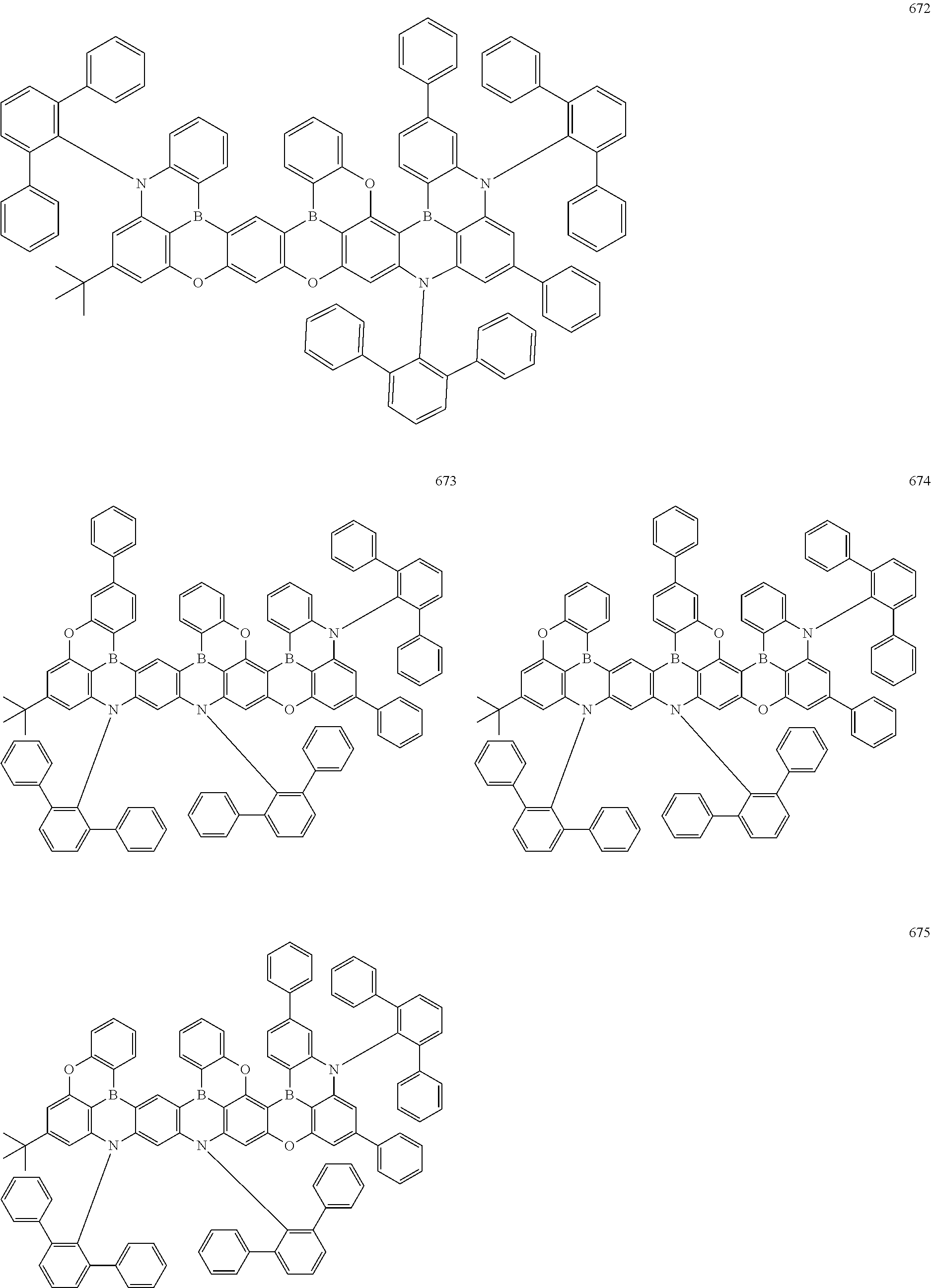

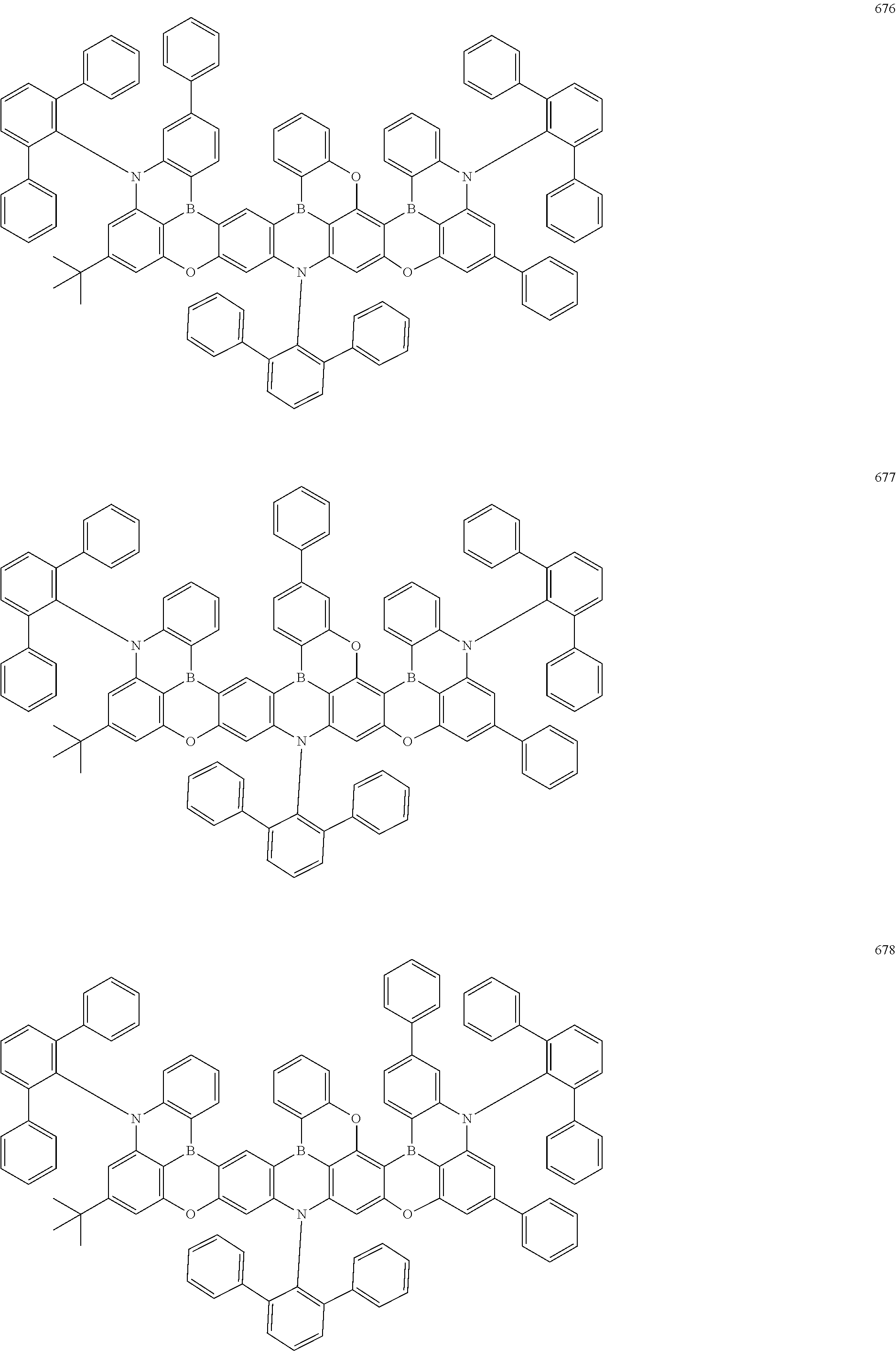

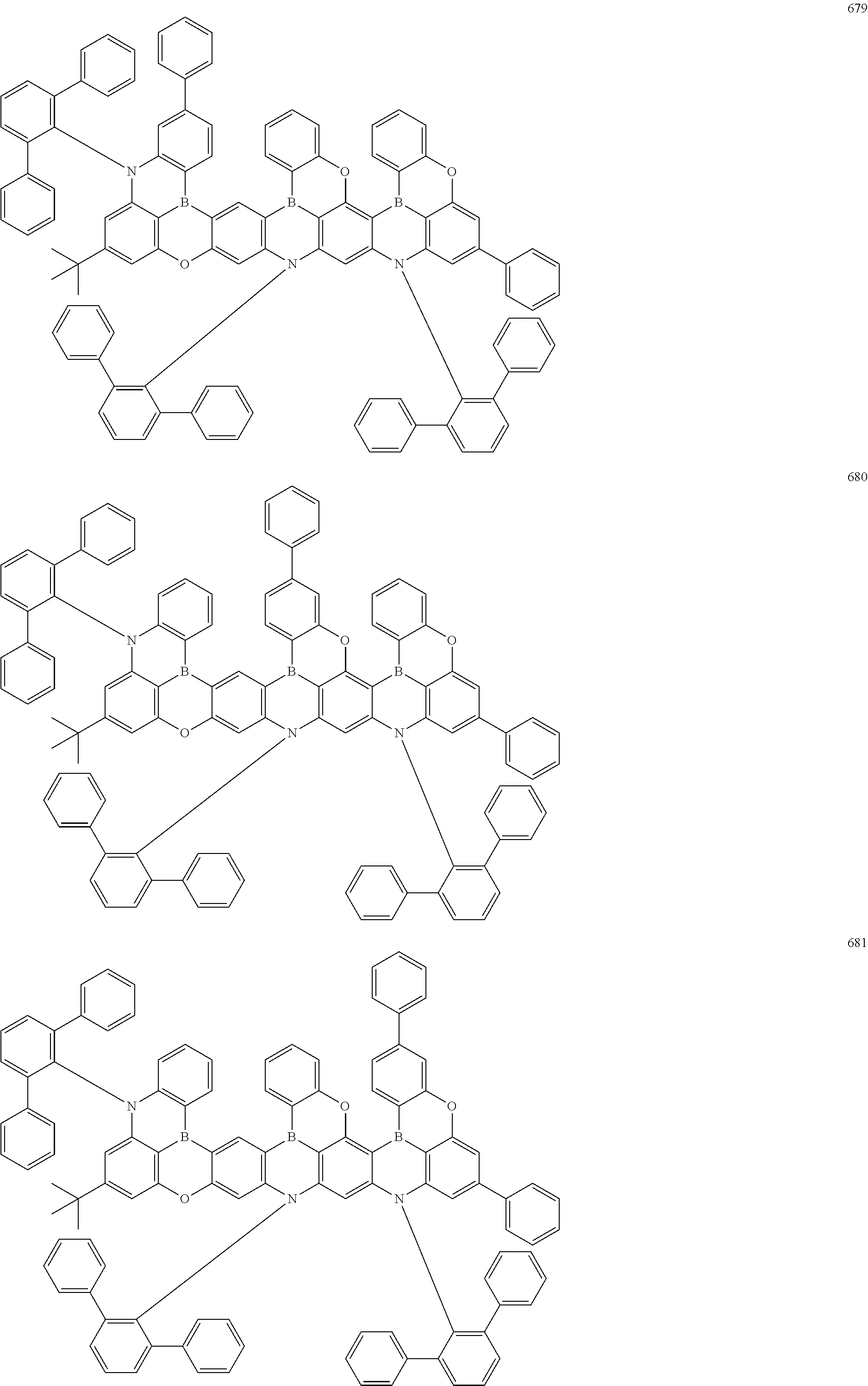

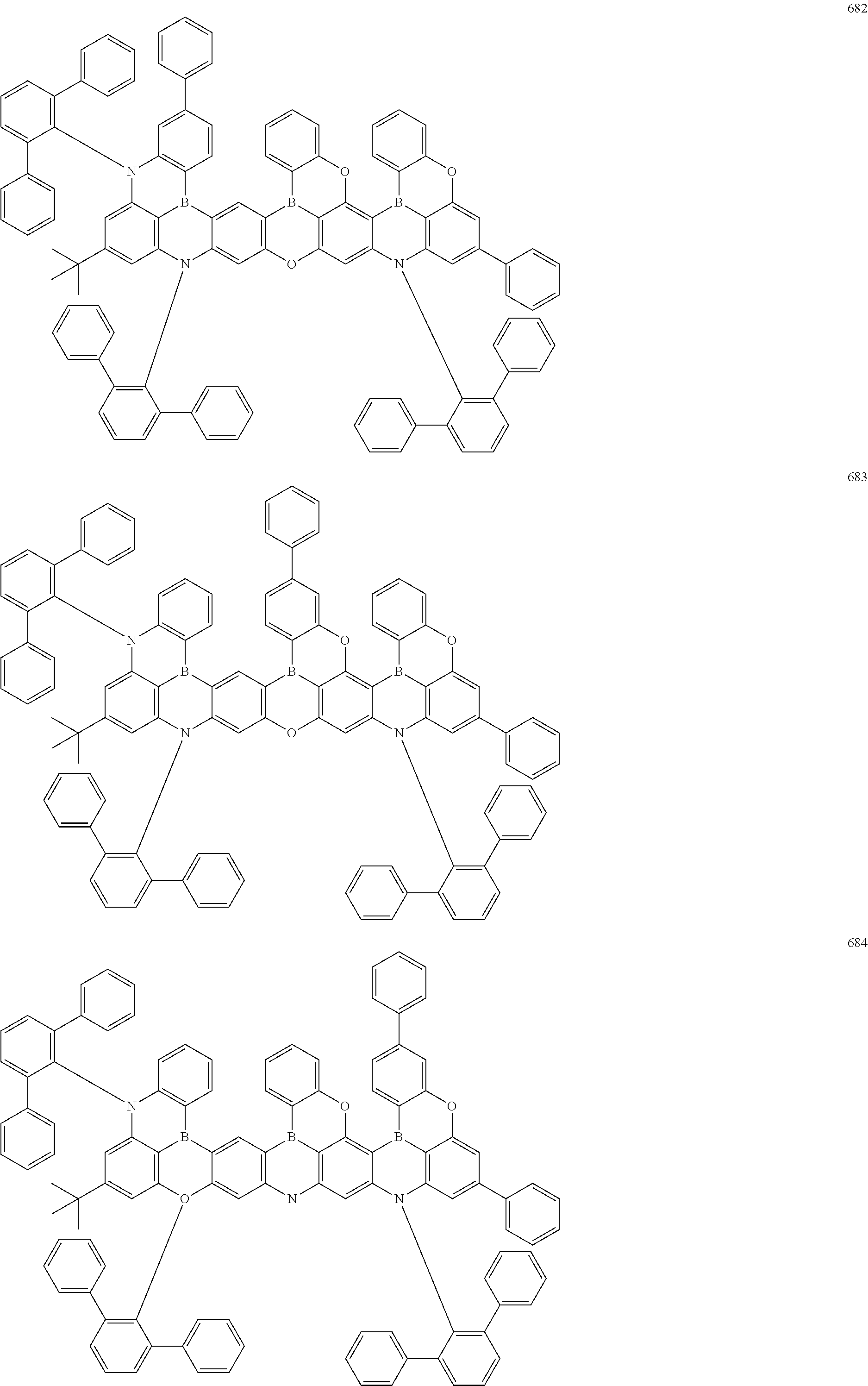

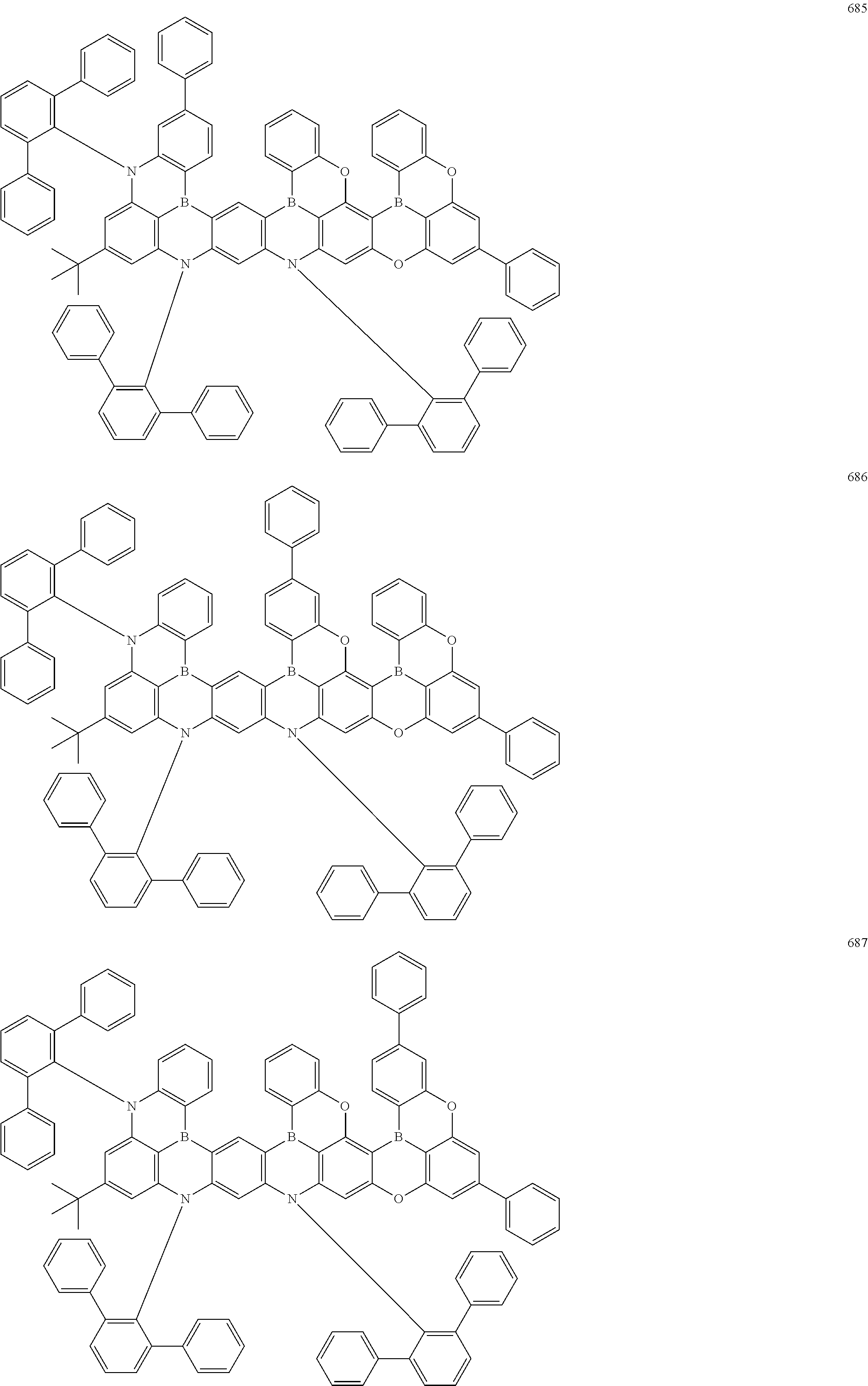

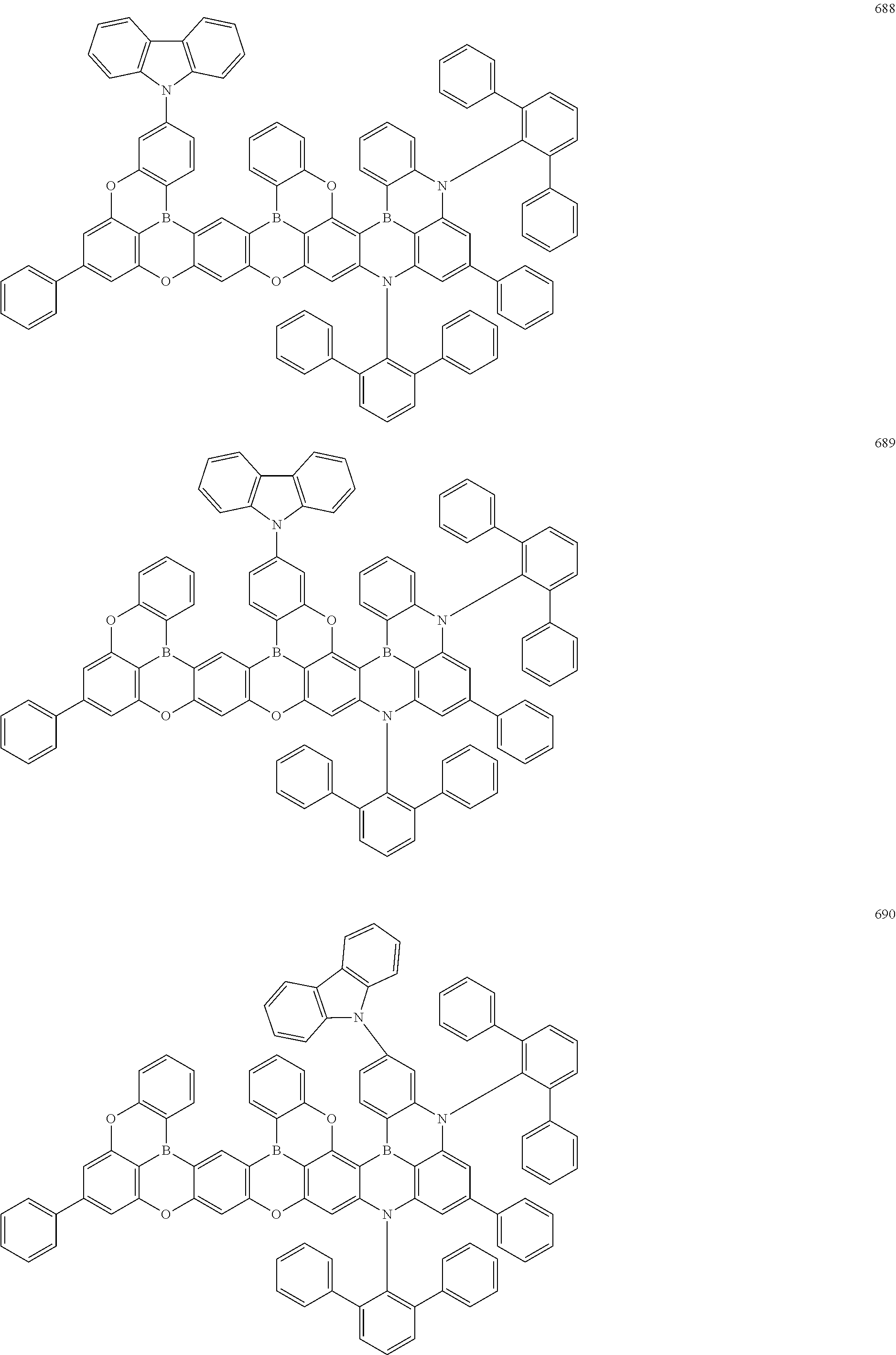

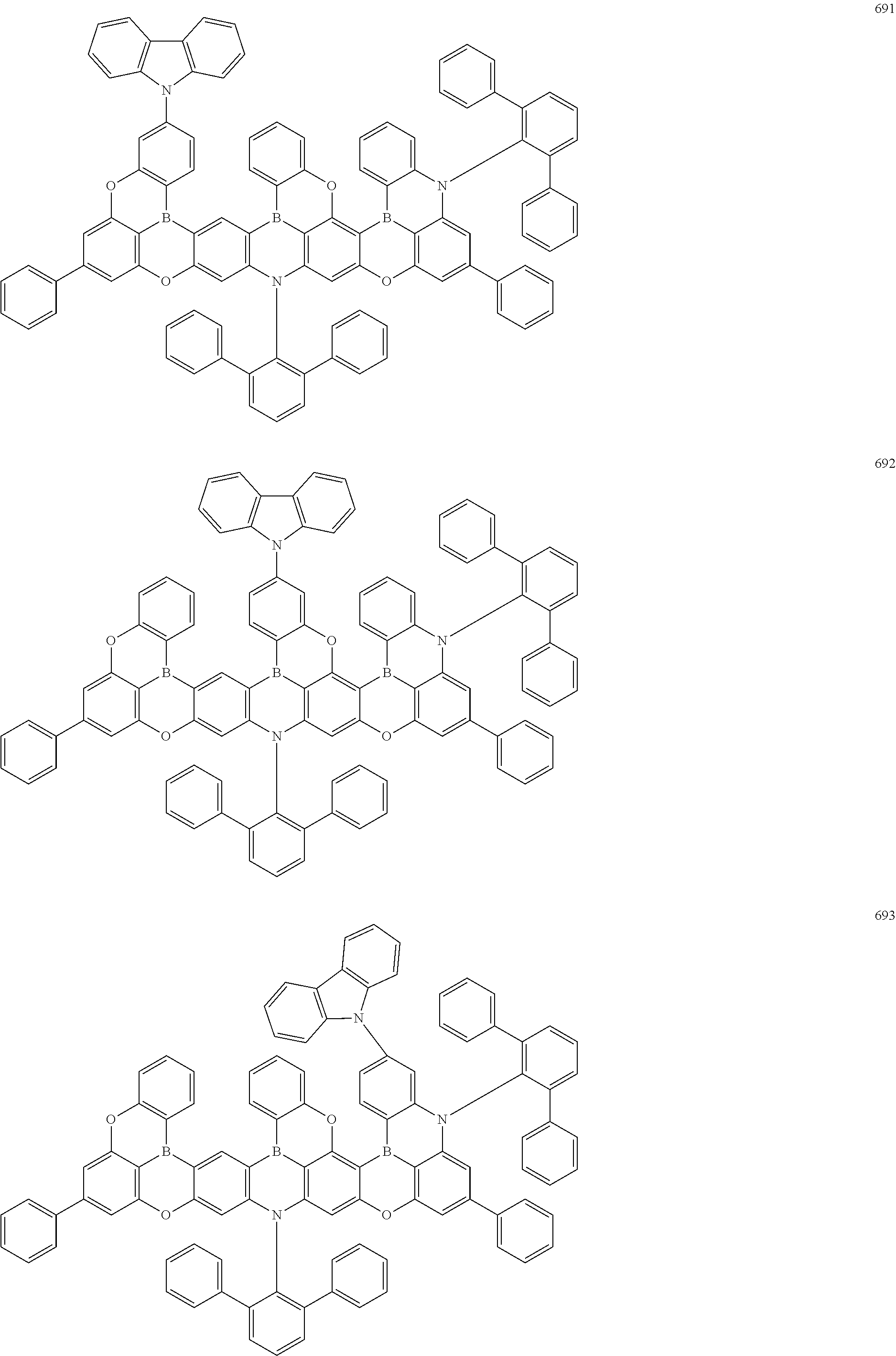

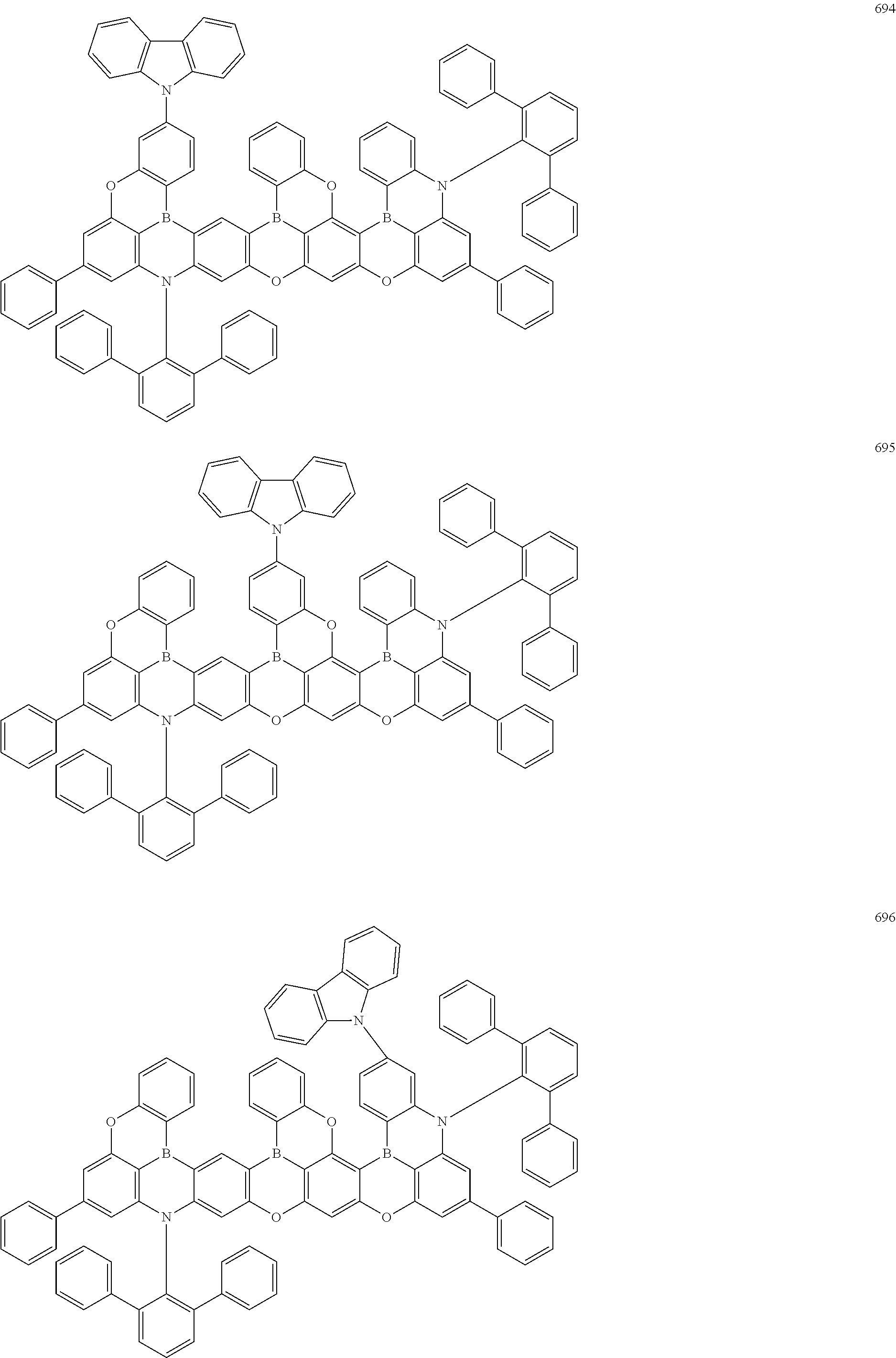

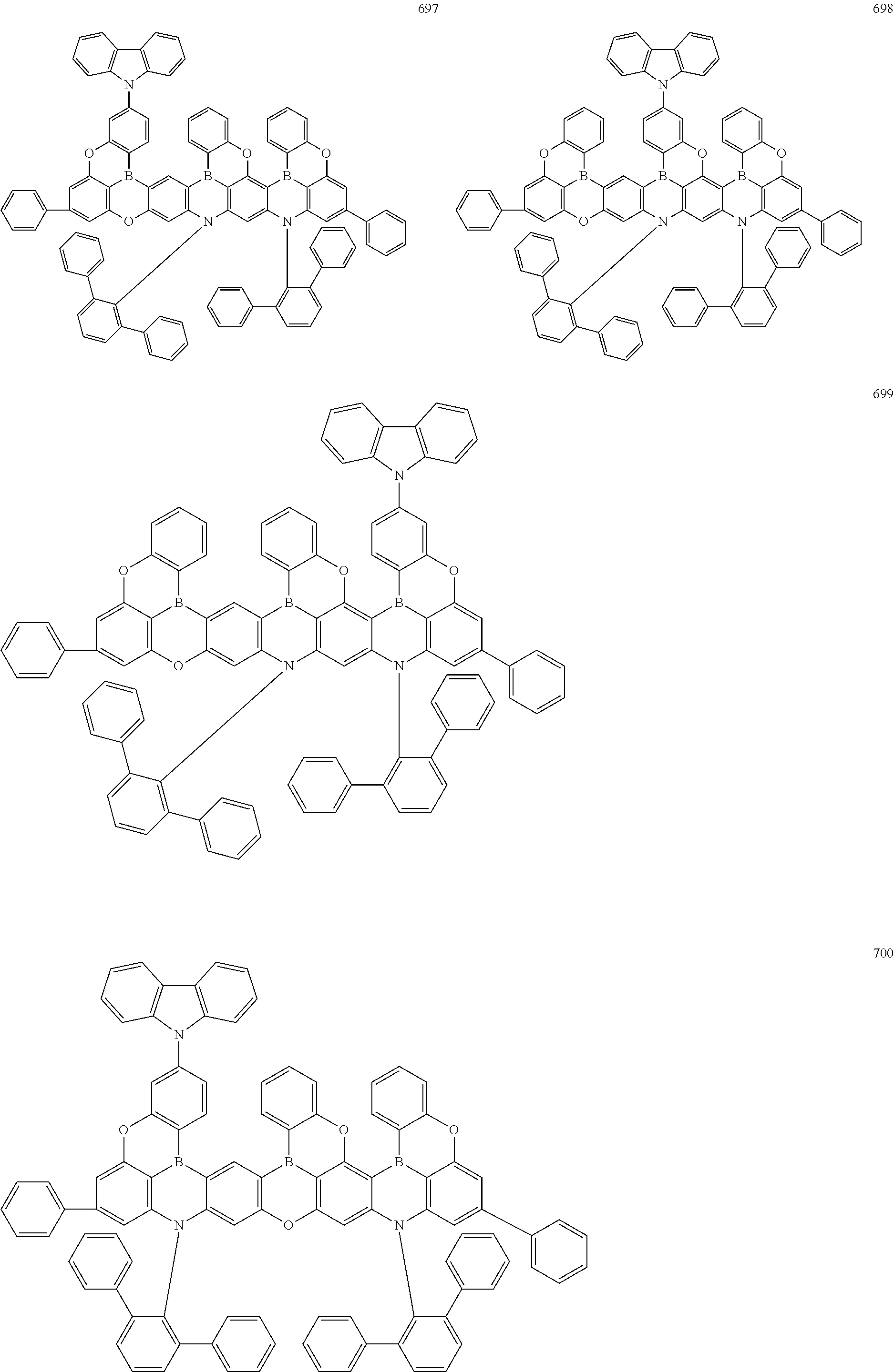

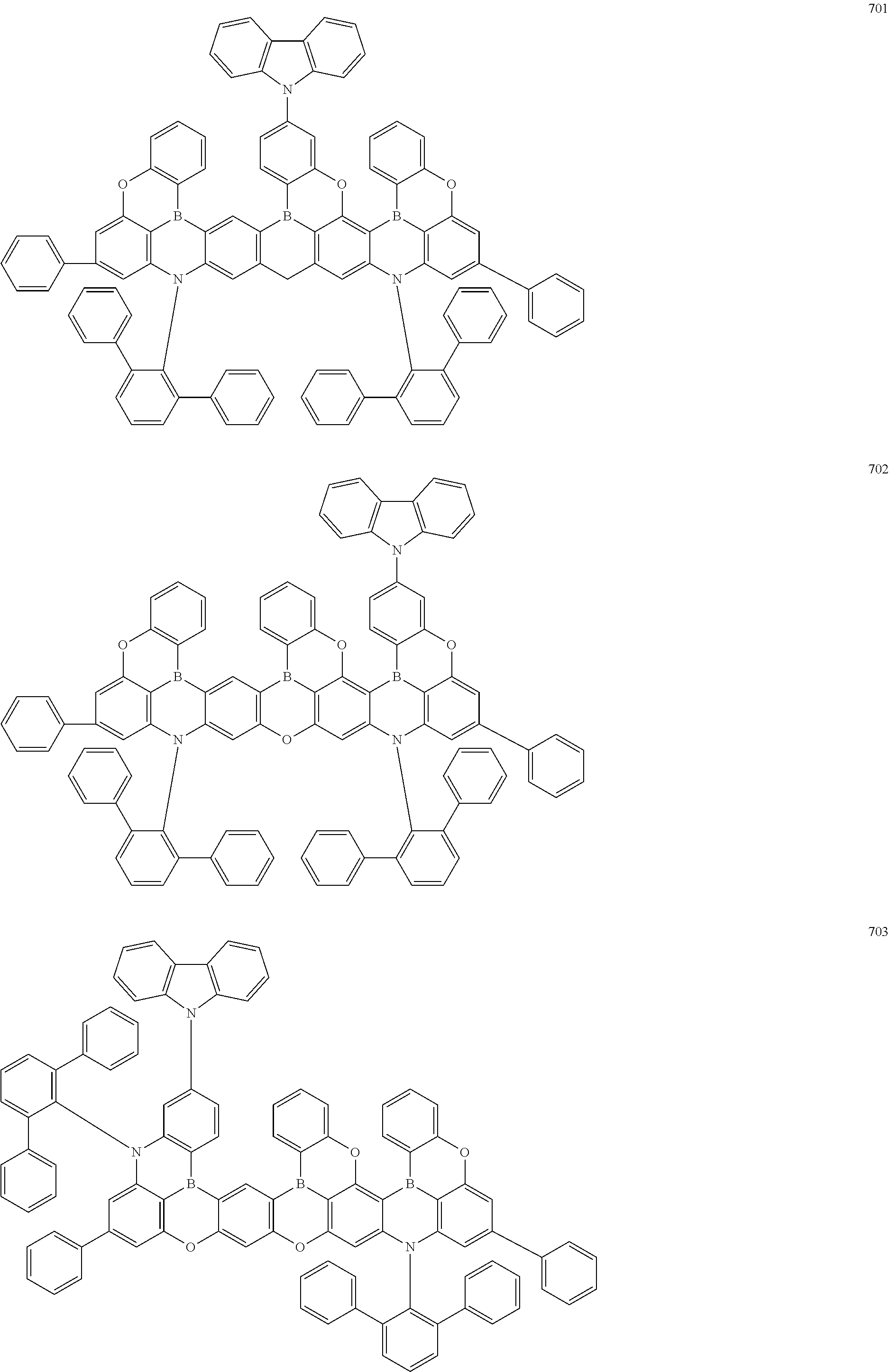

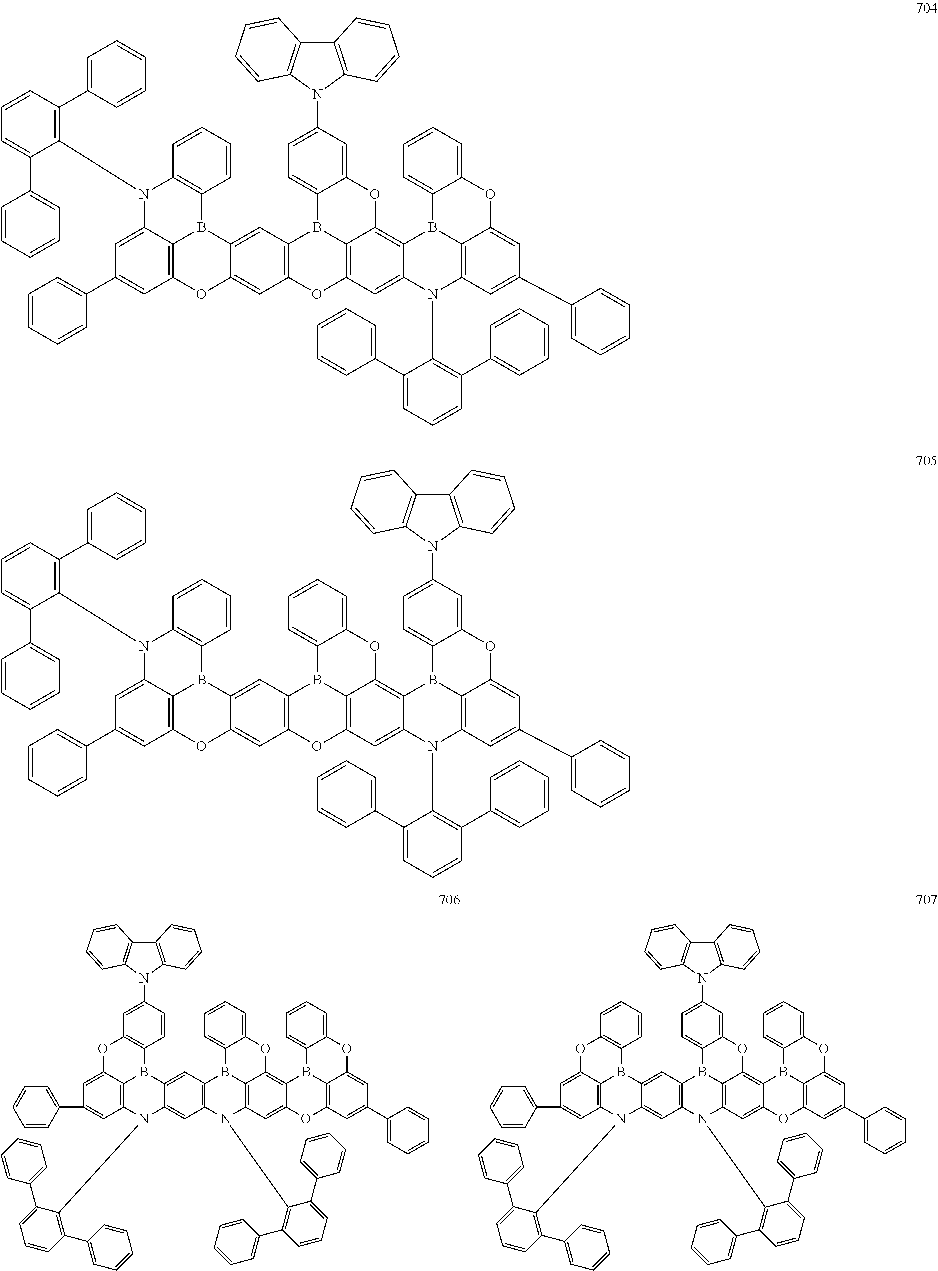

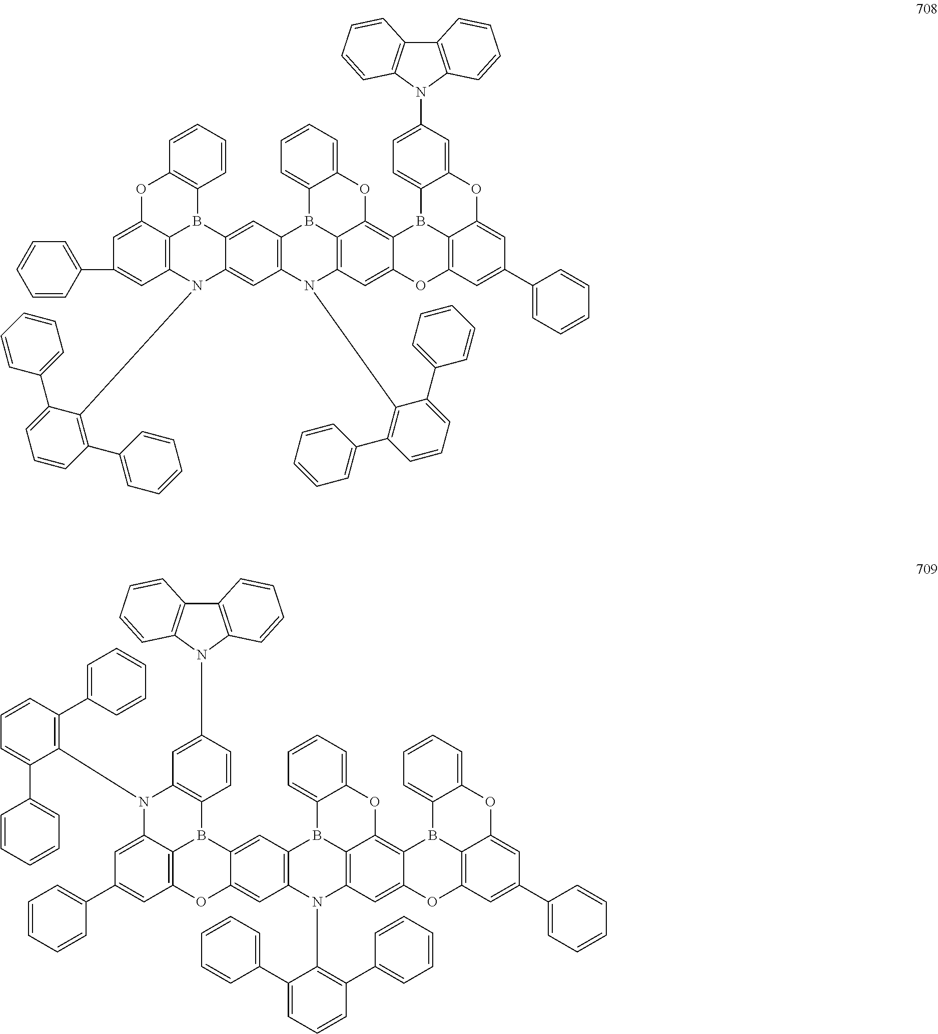 [SMILES: c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccccc2O4)cc1 ; c1ccc(-c2cc3c4c(c2)Oc2cc5c6c(c2B4c2ccccc2O3)Oc2ccccc2B6c2cc3c(cc2N5c2c(-c4ccccc4)cccc2-c2ccccc2)Oc2cc(-c4ccccc4)cc4c2B3c2ccc(-n3c5ccccc5c5ccccc53)cc2N4c2c(-c3ccccc3)cccc2-c2ccccc2)cc1]

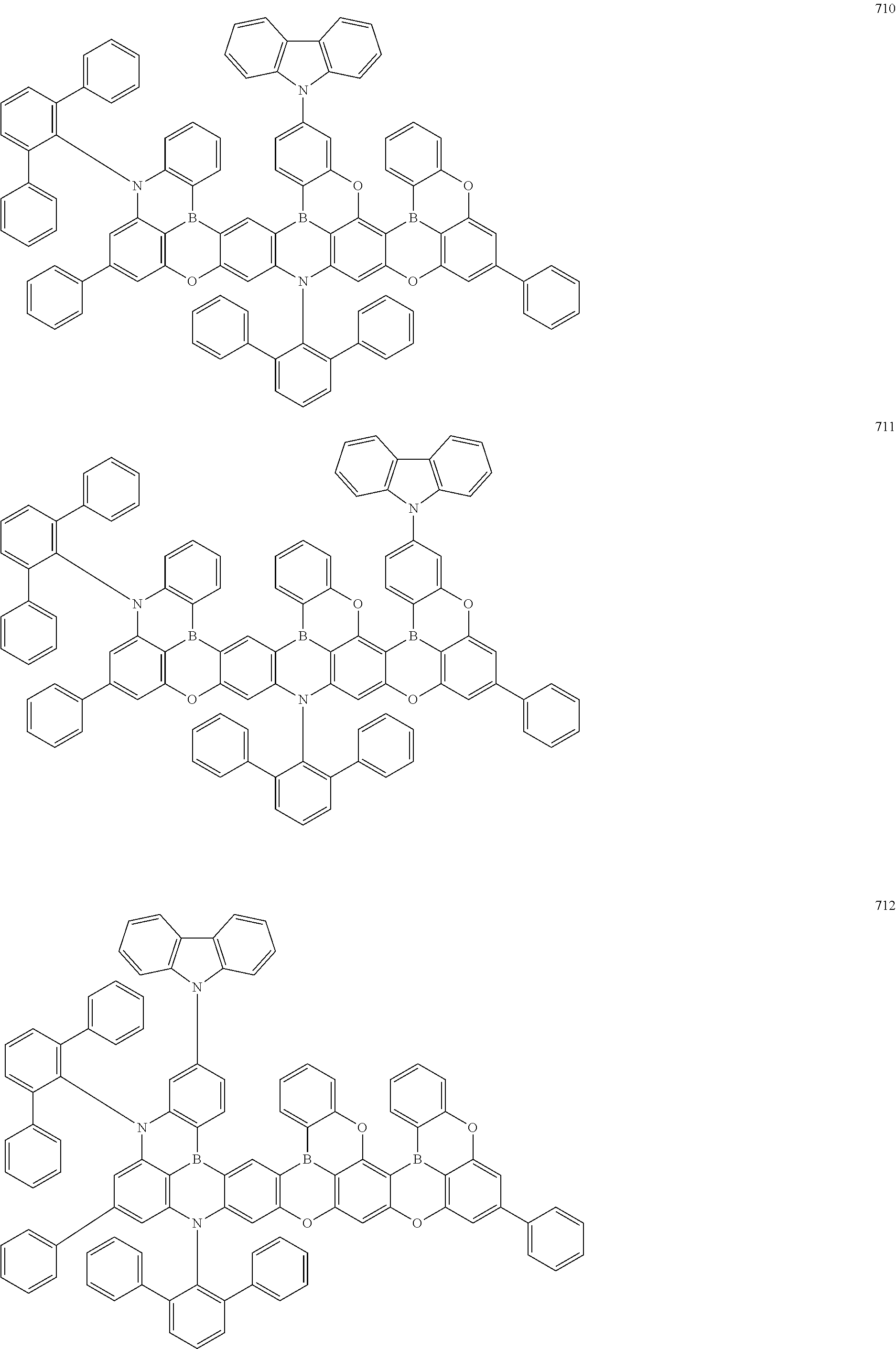

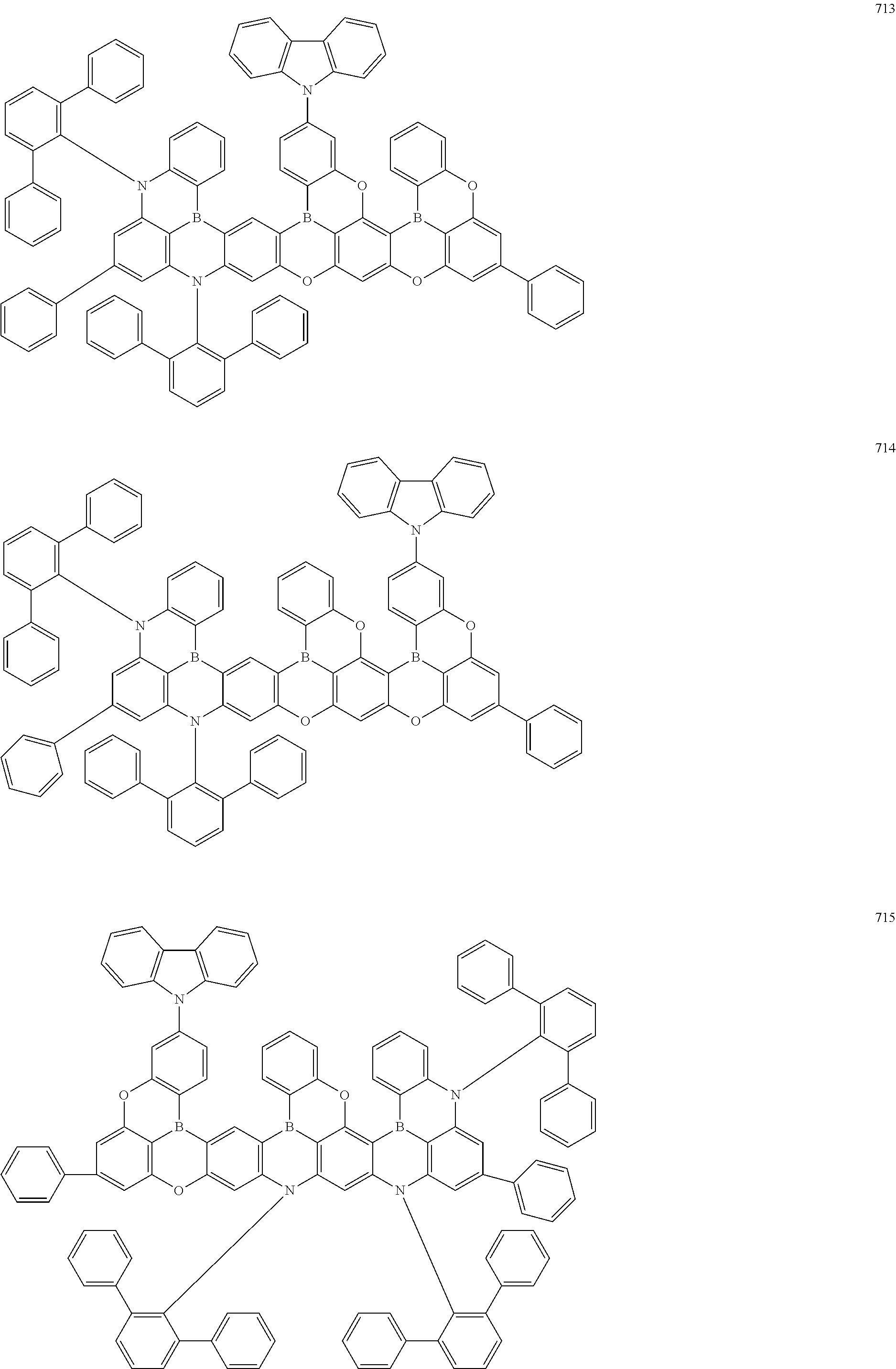

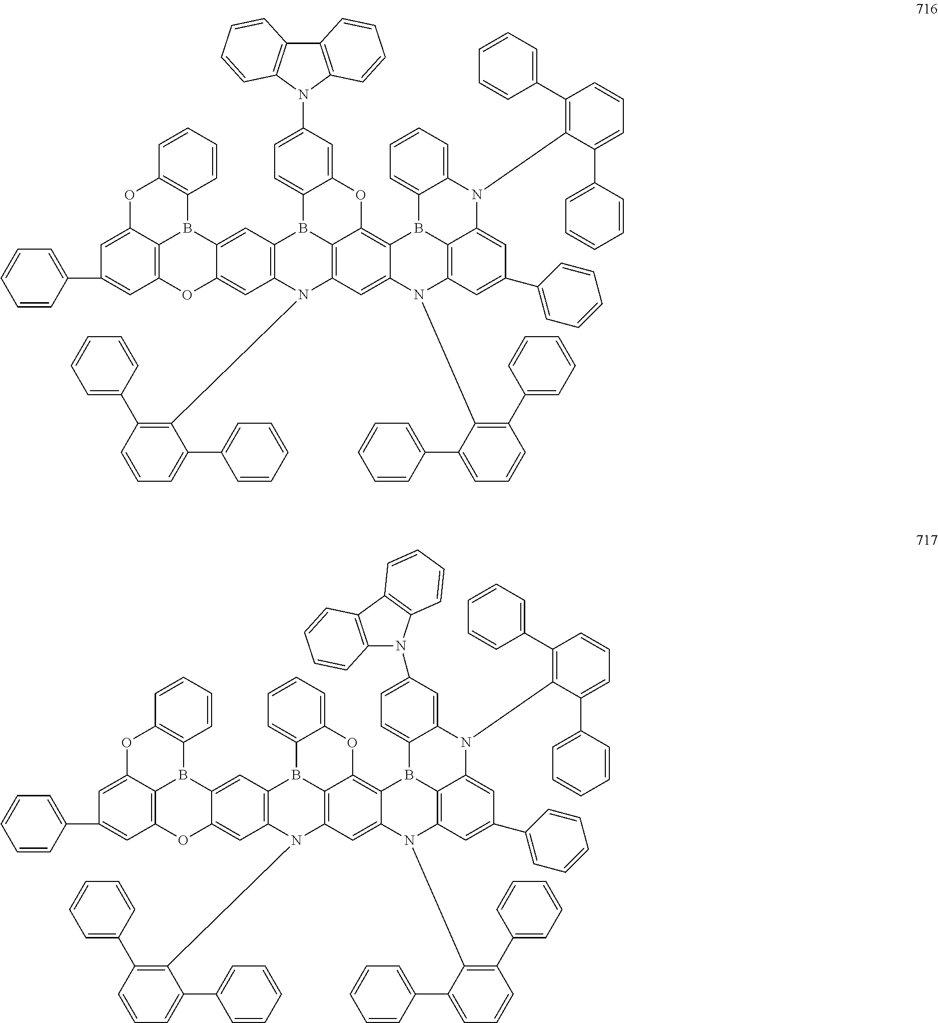 [SMILES: c1ccc(-c2cc3c4c(c2)Oc2cc5c(cc2B4c2ccccc2O3)B2c3ccc(-n4c6ccccc6c6ccccc64)cc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1 ; c1ccc(-c2cc3c4c(c2)Oc2cc5c(cc2B4c2ccccc2O3)B2c3ccccc3Oc3c2c(cc2c3B3c4ccc(-n6c7ccccc7c7ccccc76)cc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1]

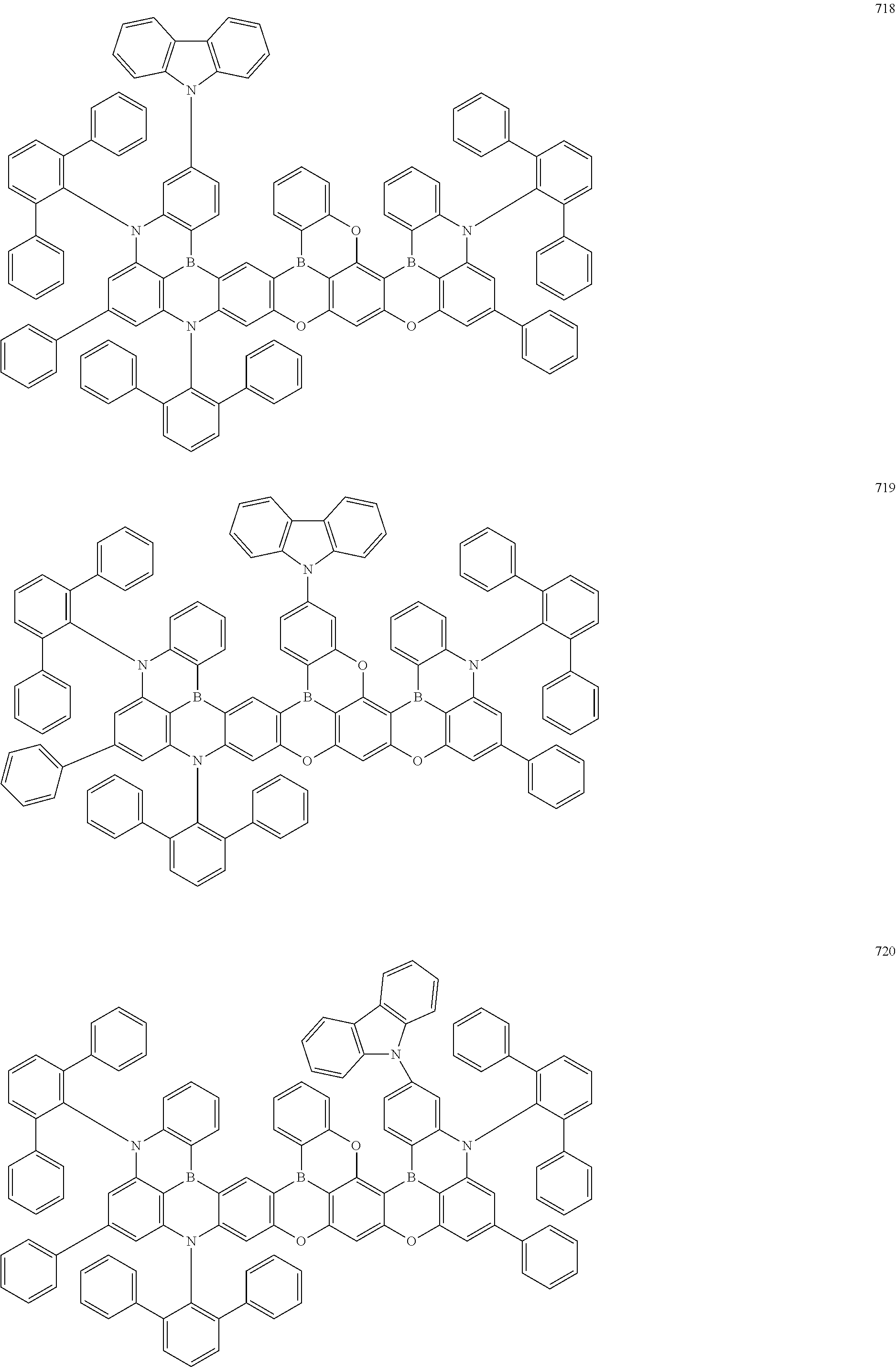

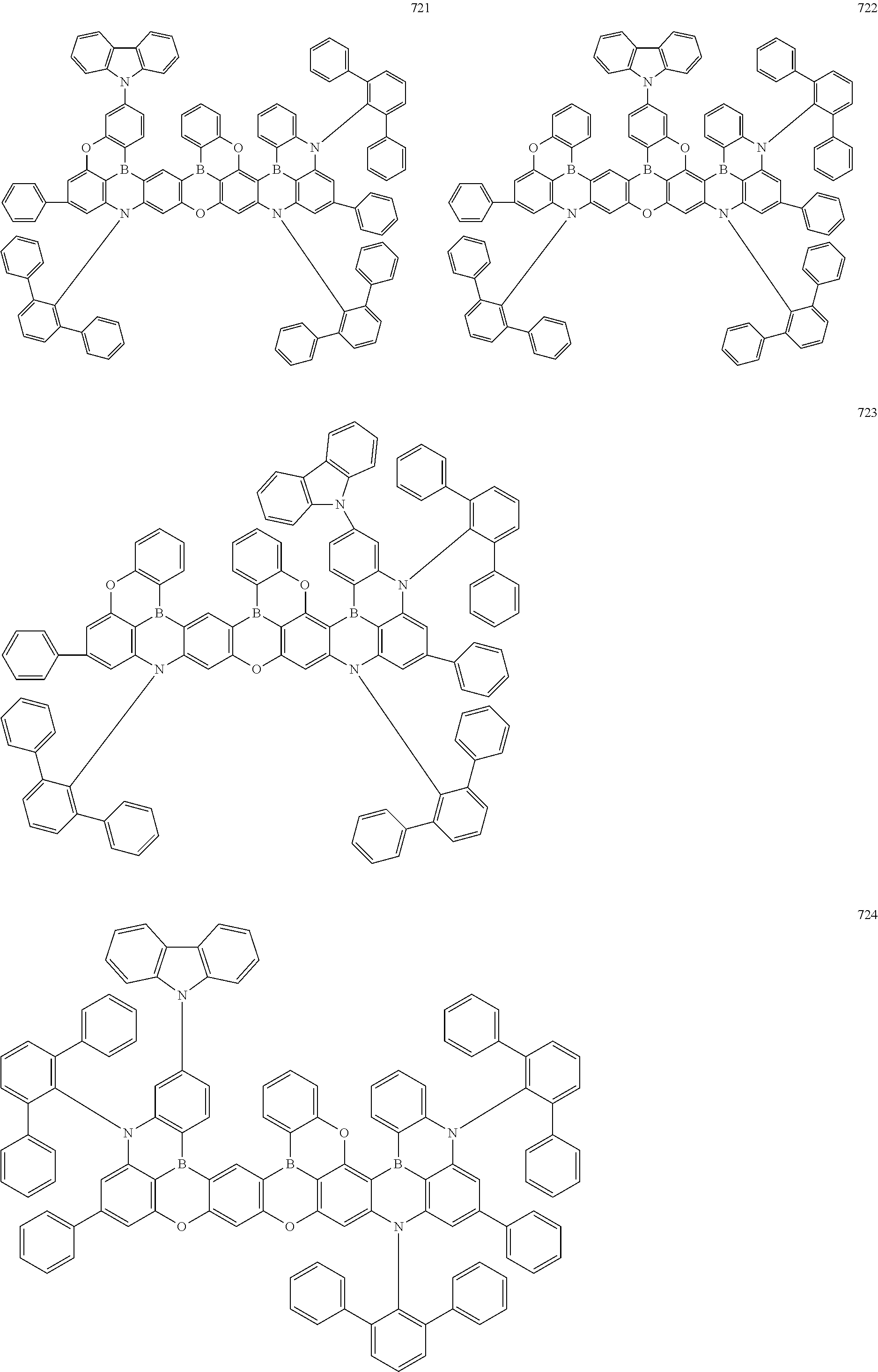

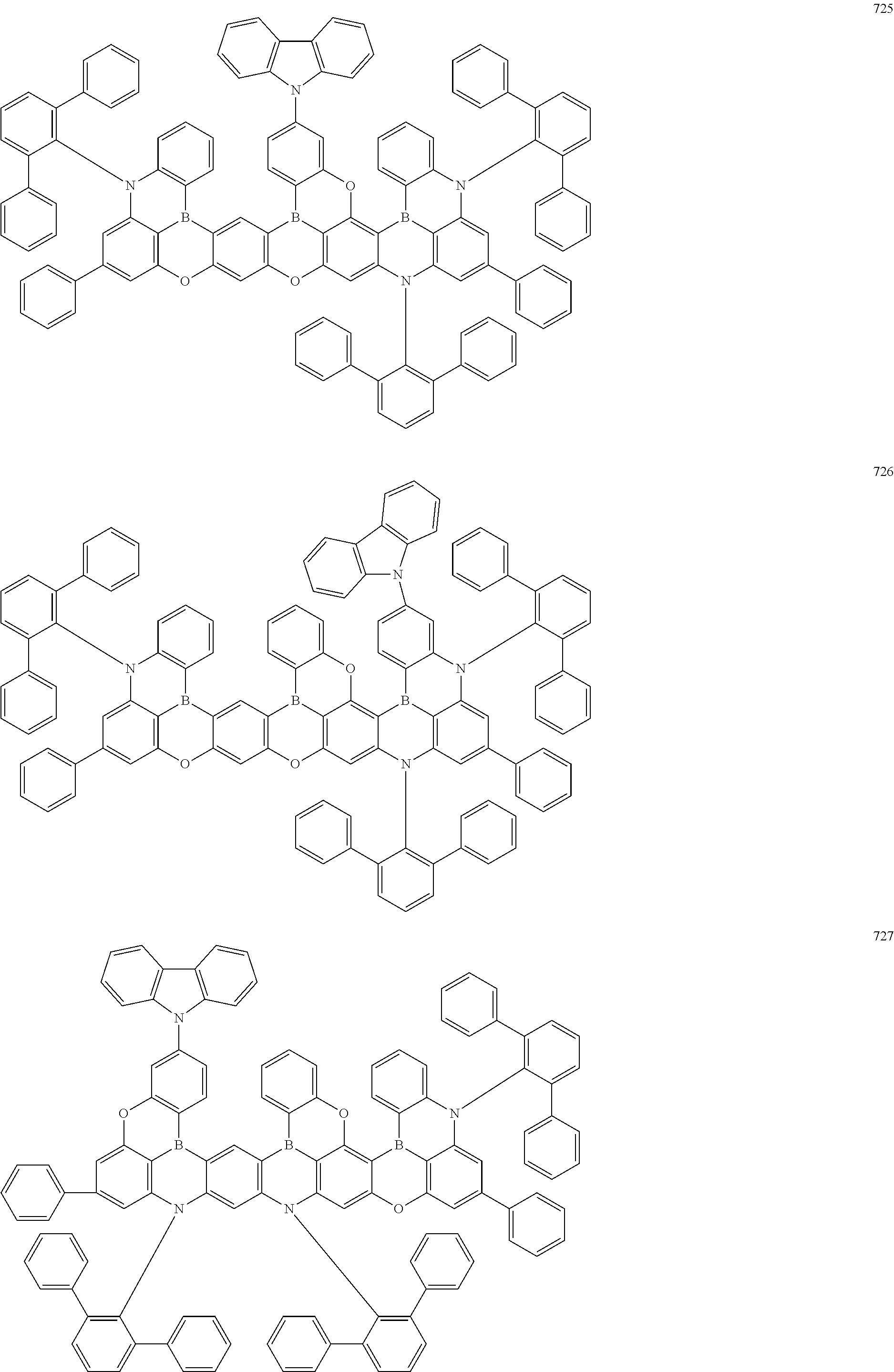

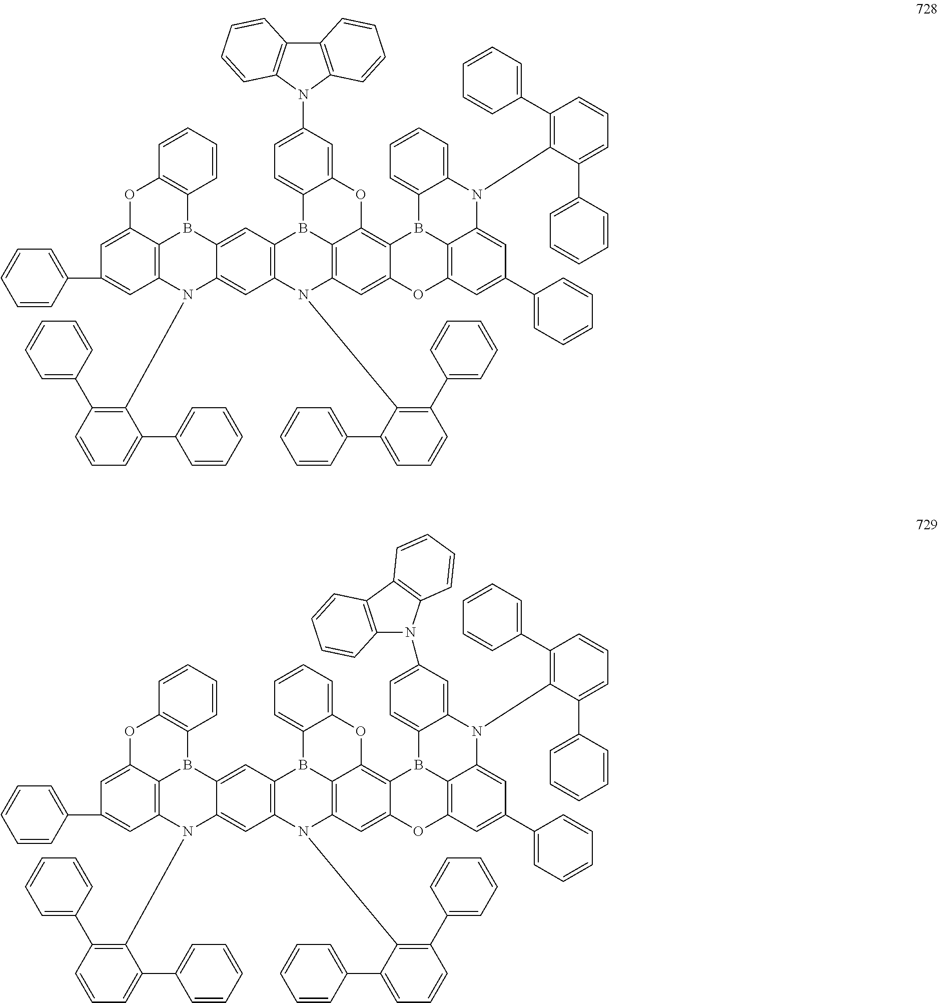 [SMILES: c1ccc(-c2cc3c4c(c2)N(c2c(-c5ccccc5)cccc2-c2ccccc2)c2cc5c(cc2B4c2ccccc2O3)B2c3ccc(-n4c6ccccc6c6ccccc64)cc3Oc3c4c(cc(c32)N5c2c(-c3ccccc3)cccc2-c2ccccc2)Oc2cc(-c3ccccc3)cc3c2B4c2ccccc2N3c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccccc2O3)B2c3ccccc3Oc3c4c(cc(c32)N5c2c(-c3ccccc3)cccc2-c2ccccc2)Oc2cc(-c3ccccc3)cc3c2B4c2ccc(-n4c5ccccc5c5ccccc54)cc2N3c2c(-c3ccccc3)cccc2-c2ccccc2)cc1]

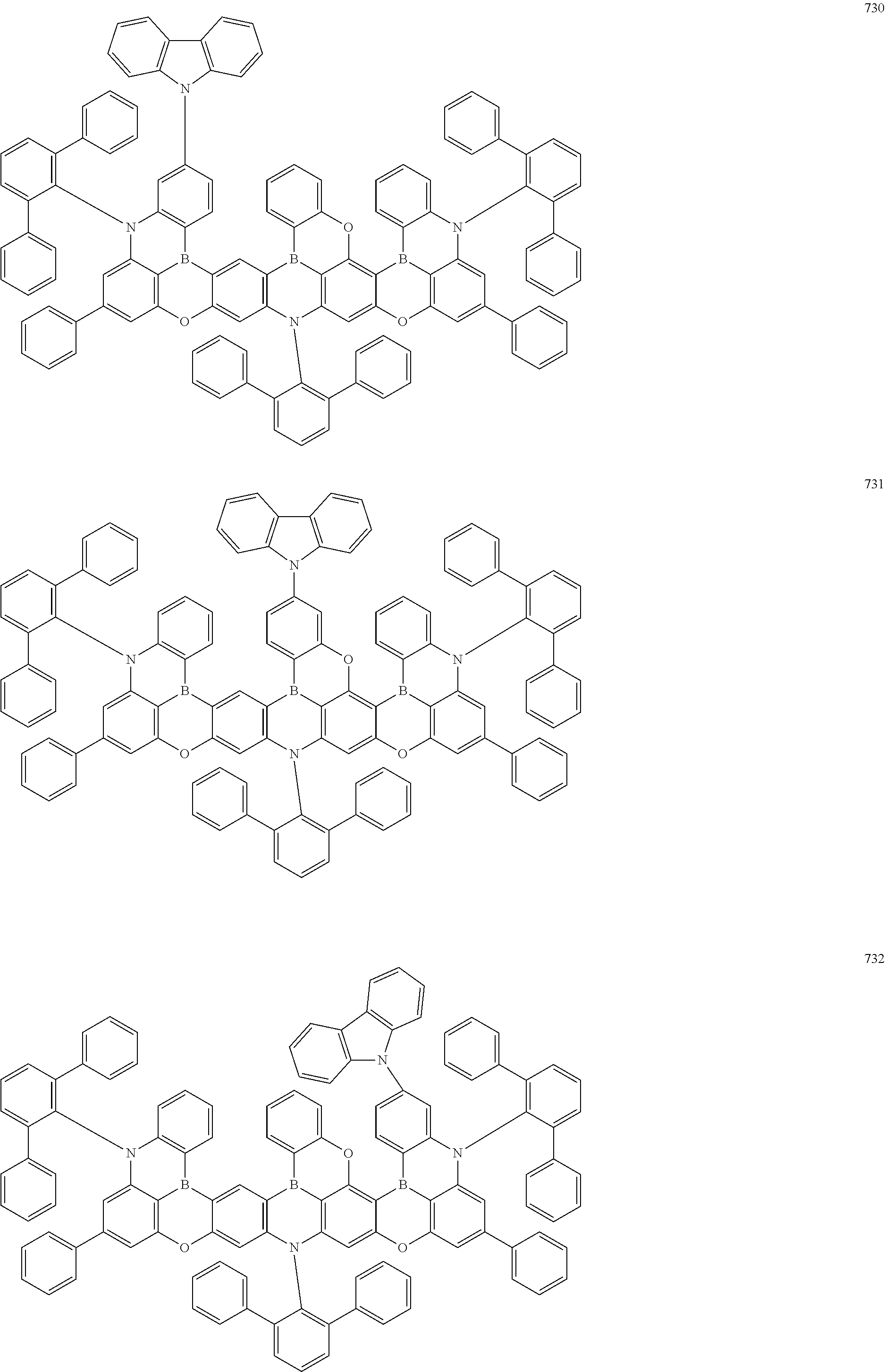

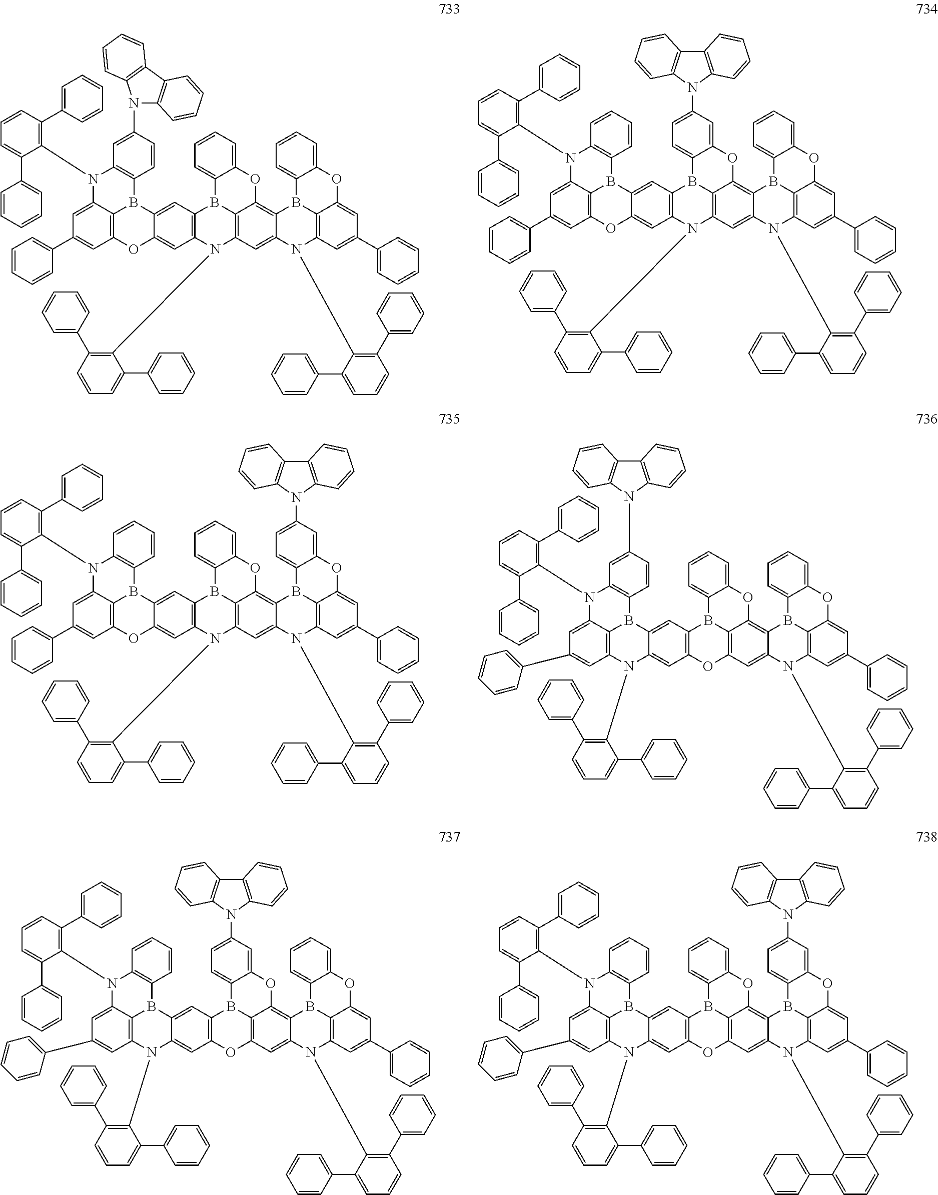

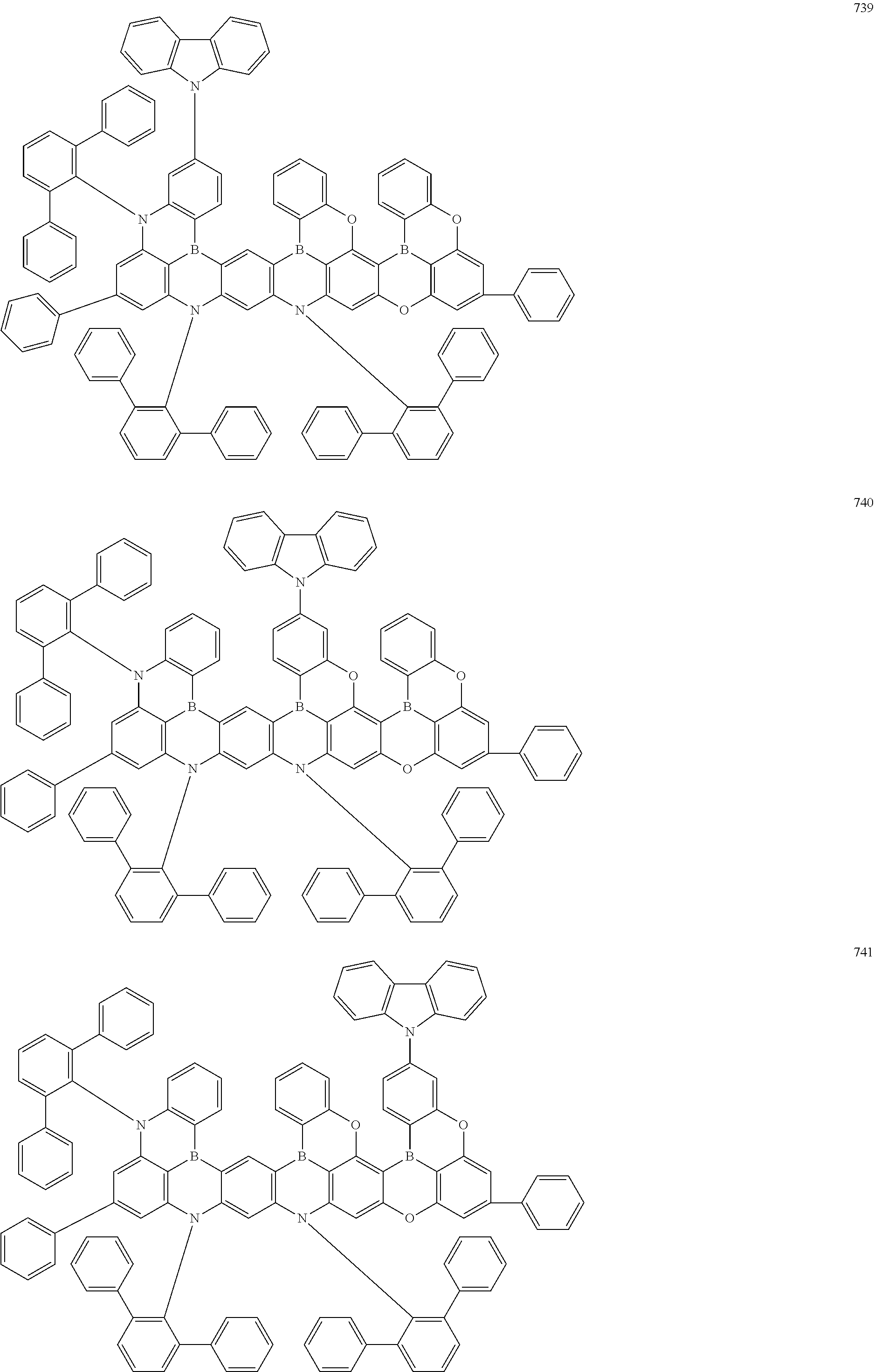

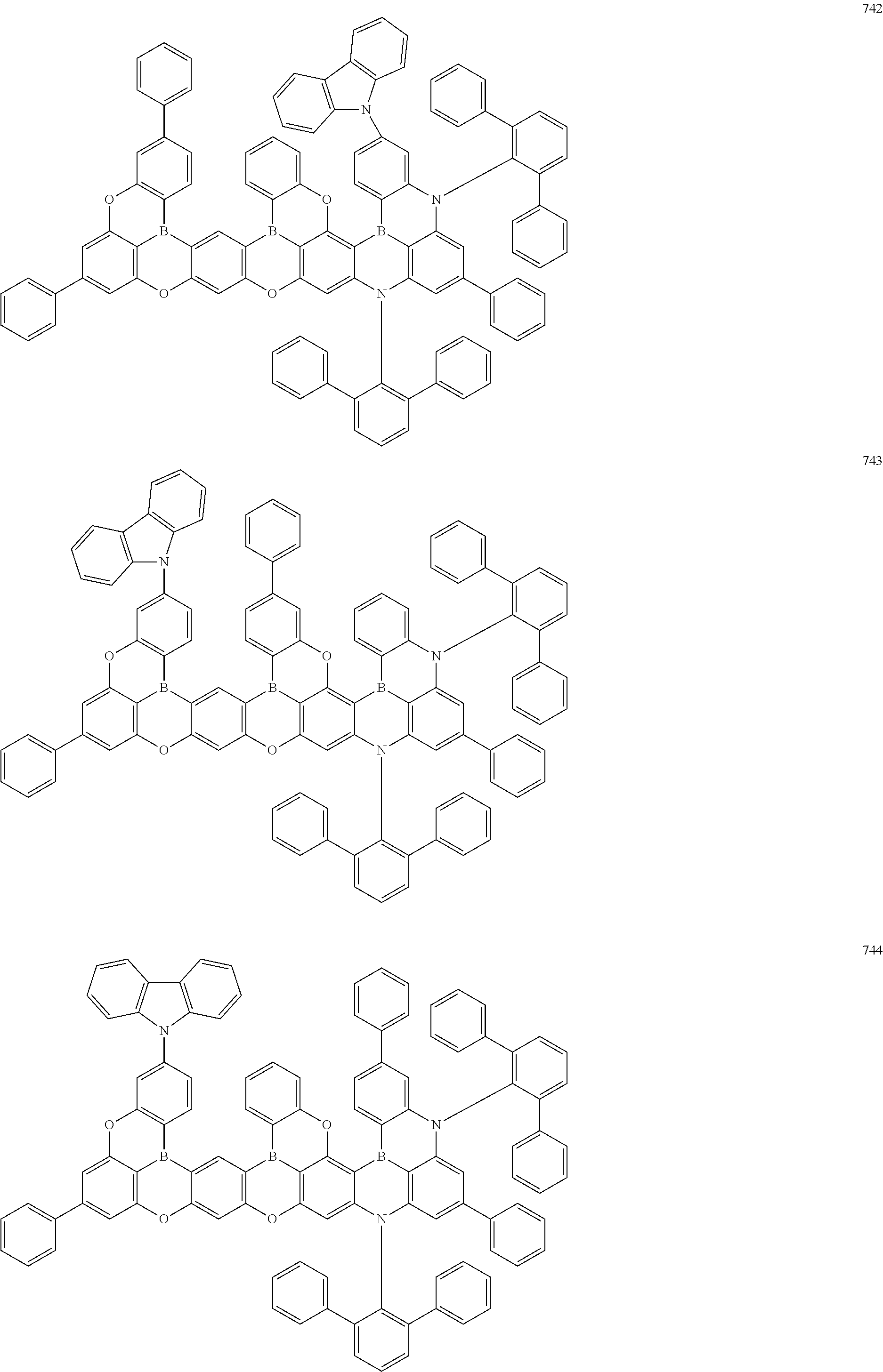

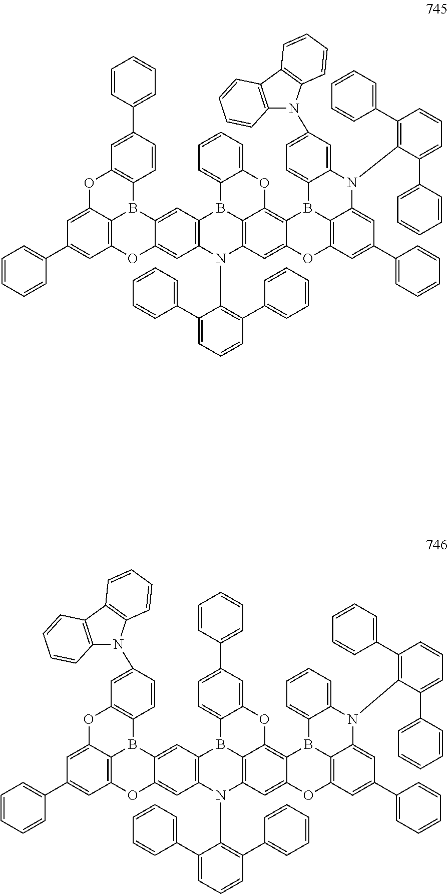 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1 ; c1ccc(-c2ccc3c(c2)Oc2c4c(cc5c2B3c2cc3c(cc2N5c2c(-c5ccccc5)cccc2-c2ccccc2)Oc2cc(-c5ccccc5)cc5c2B3c2ccc(-n3c6ccccc6c6ccccc63)cc2O5)Oc2cc(-c3ccccc3)cc3c2B4c2ccccc2N3c2c(-c3ccccc3)cccc2-c2ccccc2)cc1]

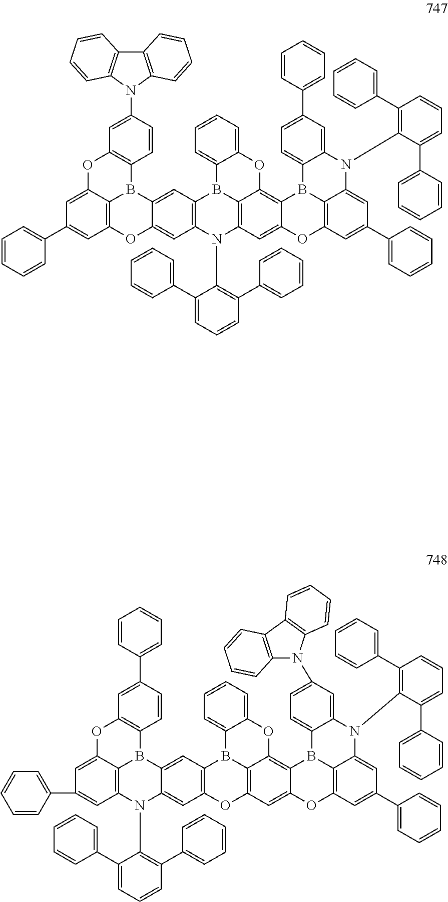 [SMILES: c1ccc(-c2cc3c4c(c2)Oc2cc5c(cc2B4c2ccc(-n4c6ccccc6c6ccccc64)cc2O3)B2c3ccccc3Oc3c4c(cc(c32)N5c2c(-c3ccccc3)cccc2-c2ccccc2)Oc2cc(-c3ccccc3)cc3c2B4c2ccc(-c4ccccc4)cc2N3c2c(-c3ccccc3)cccc2-c2ccccc2)cc1 ; c1ccc(-c2ccc3c(c2)Oc2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1]

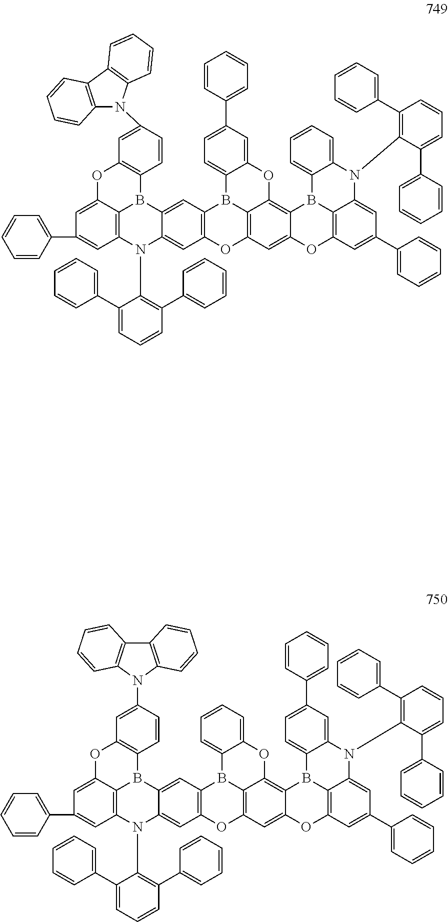 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)O5)Oc2cc5c(cc2B34)B2c3ccc(-n4c6ccccc6c6ccccc64)cc3Oc3cc(-c4ccccc4)cc(c32)N5c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccc(-n5c6ccccc6c6ccccc65)cc2O3)O4)cc1]

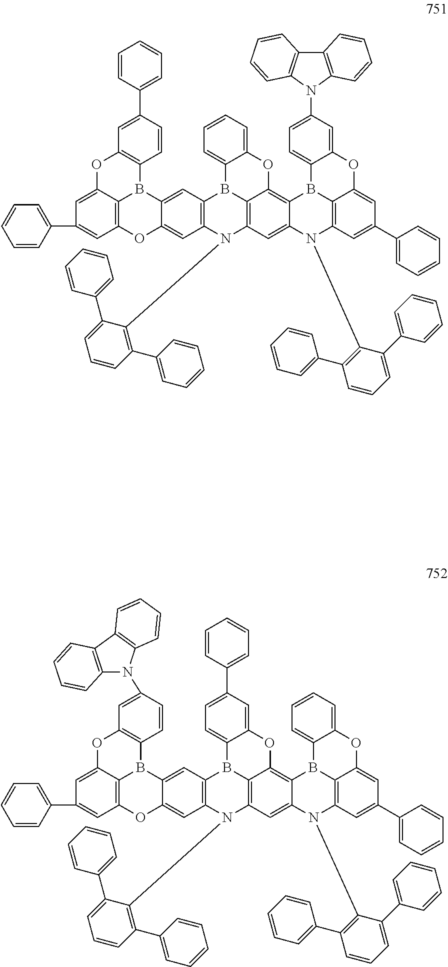 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3Oc3cc(-c4ccccc4)cc(c32)O5)cc1]

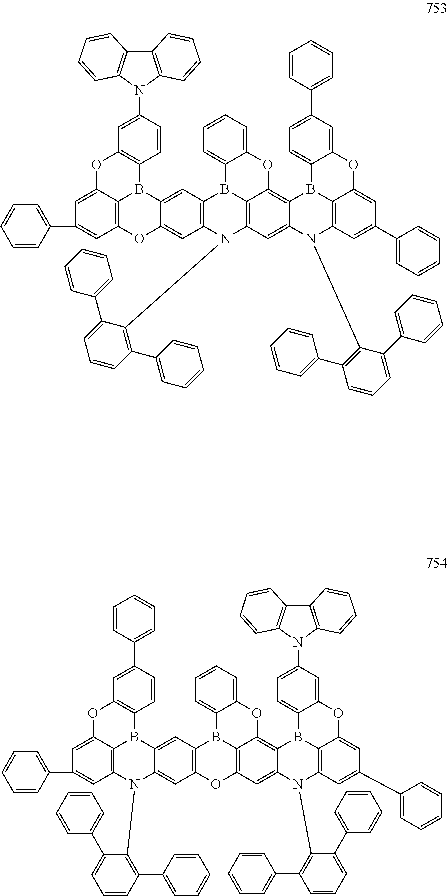 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2O3)N4c2c(-c3ccccc3)cccc2-c2ccccc2)cc1 ; c1ccc(-c2ccc3c(c2)Oc2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1]

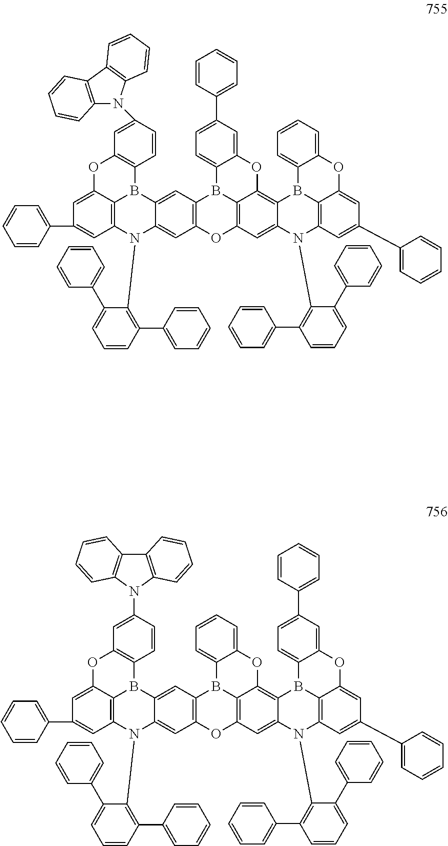 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3Oc3cc(-c4ccccc4)cc(c32)N5c2c(-c3ccccc3)cccc2-c2ccccc2)cc1 ; c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccc(-n5c6ccccc6c6ccccc65)cc2O3)N4c2c(-c3ccccc3)cccc2-c2ccccc2)cc1]

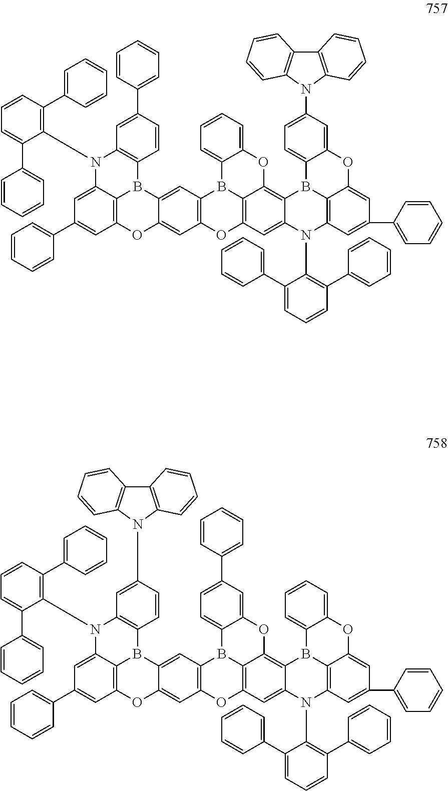 [SMILES: c1ccc(-c2ccc3c(c2)N(c2c(-c4ccccc4)cccc2-c2ccccc2)c2cc(-c4ccccc4)cc4c2B3c2cc3c(cc2O4)Oc2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)O5)cc1]

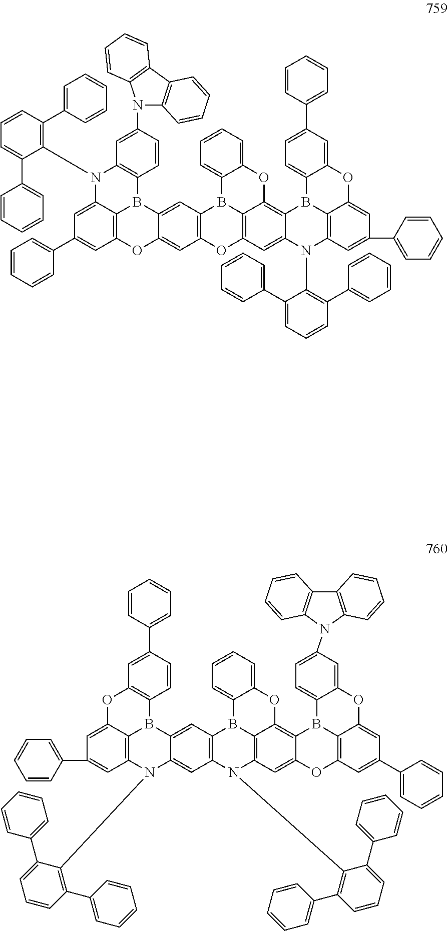 [SMILES: c1ccc(-c2ccc3c(c2)Oc2cc(-c4ccccc4)cc4c2B3c2c(cc3c5c2Oc2ccccc2B5c2cc5c(cc2O3)Oc2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1 ; c1ccc(-c2ccc3c(c2)Oc2cc(-c4ccccc4)cc4c2B3c2cc3c(cc2N4c2c(-c4ccccc4)cccc2-c2ccccc2)N(c2c(-c4ccccc4)cccc2-c2ccccc2)c2cc4c(c5c2B3c2ccccc2O5)B2c3ccc(-n5c6ccccc6c6ccccc65)cc3Oc3cc(-c5ccccc5)cc(c32)O4)cc1]

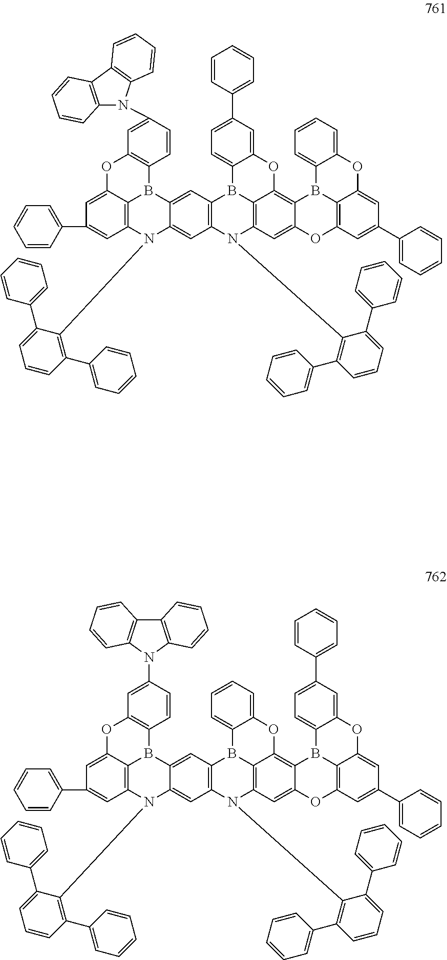 [SMILES: c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccc(-n3c6ccccc6c6ccccc63)cc2O5)Oc2cc(-c3ccccc3)cc3c2B4c2ccccc2O3)cc1 ; c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2cc(-c3ccccc3)cc3c2B5c2ccc(-n5c6ccccc6c6ccccc65)cc2O3)O4)cc1]

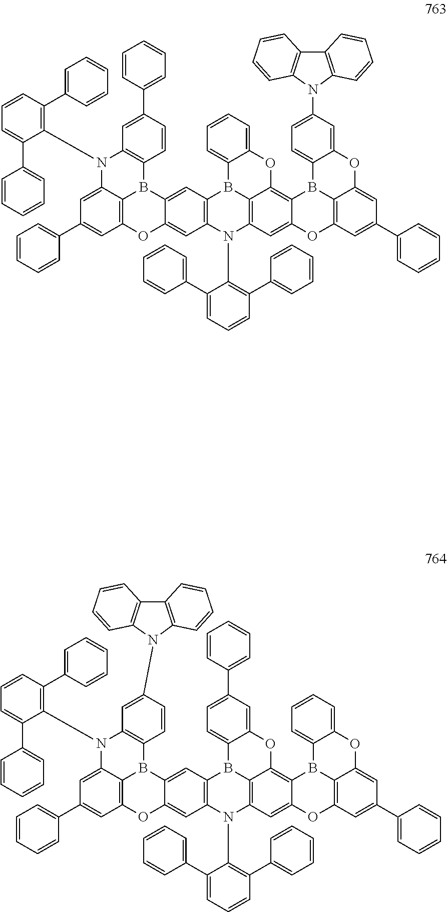 [SMILES: c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)Oc2cc(-c4ccccc4)cc4c2B3c2ccc(-c3ccccc3)cc2N4c2c(-c3ccccc3)cccc2-c2ccccc2)cc1 ; c1ccc(-c2ccc3c(c2)Oc2c4c(cc5c2B3c2cc3c(cc2N5c2c(-c5ccccc5)cccc2-c2ccccc2)Oc2cc(-c5ccccc5)cc5c2B3c2ccc(-n3c6ccccc6c6ccccc63)cc2N5c2c(-c3ccccc3)cccc2-c2ccccc2)Oc2cc(-c3ccccc3)cc3c2B4c2ccccc2O3)cc1]

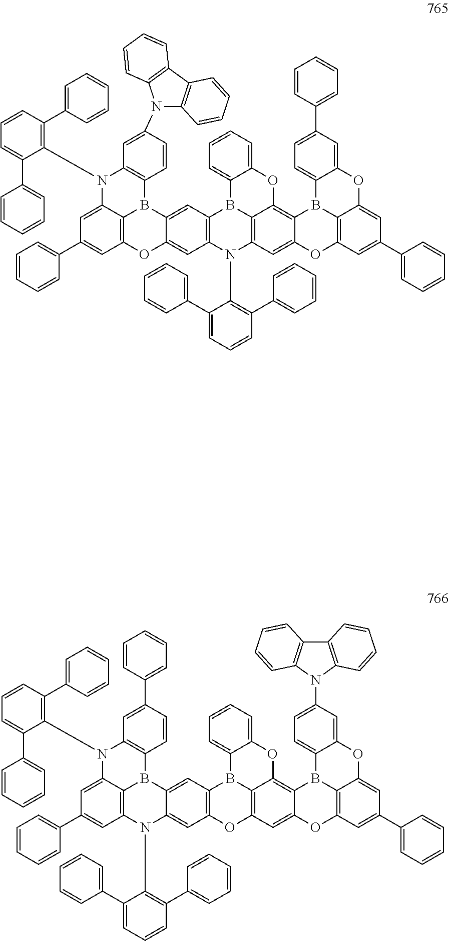 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2N3c2c(-c3ccccc3)cccc2-c2ccccc2)O4)cc1 ; c1ccc(-c2cc3c4c(c2)Oc2cc5c6c(c2B4c2ccc(-n4c7ccccc7c7ccccc74)cc2O3)Oc2ccccc2B6c2cc3c(cc2O5)N(c2c(-c4ccccc4)cccc2-c2ccccc2)c2cc(-c4ccccc4)cc4c2B3c2ccc(-c3ccccc3)cc2N4c2c(-c3ccccc3)cccc2-c2ccccc2)cc1]

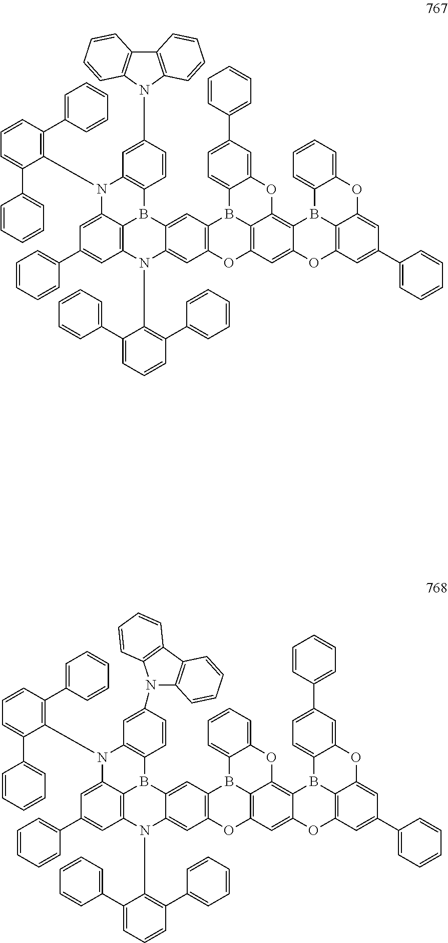 [SMILES: c1ccc(-c2ccc3c(c2)Oc2c4c(cc5c2B2c6ccccc6Oc6cc(-c7ccccc7)cc(c62)O5)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)N5c2c(-c3ccccc3)cccc2-c2ccccc2)cc1 ; c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccc(-n5c6ccccc6c6ccccc65)cc2N3c2c(-c3ccccc3)cccc2-c2ccccc2)O4)cc1]

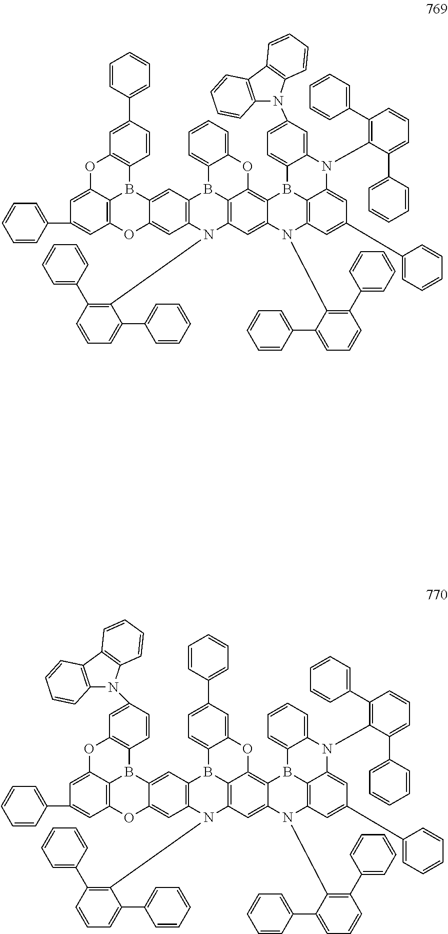 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3Oc3cc(-c4ccccc4)cc(c32)O5)cc1]

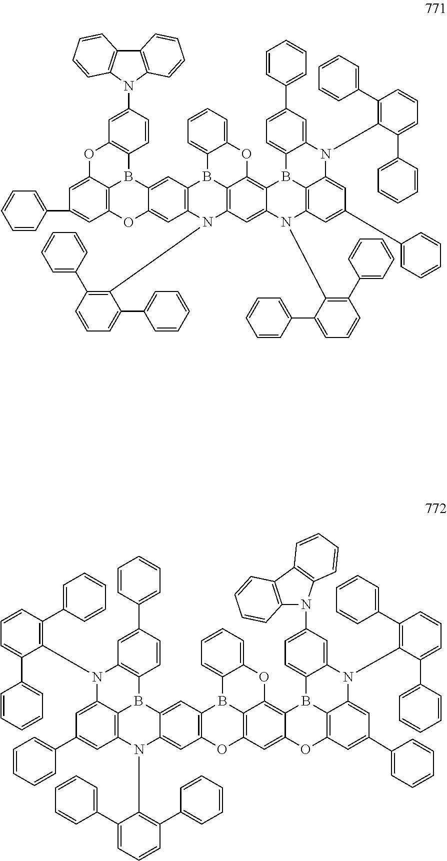 [SMILES: c1ccc(-c2cc3c4c(c2)Oc2cc5c(cc2B4c2ccc(-n4c6ccccc6c6ccccc64)cc2O3)B2c3ccccc3Oc3c2c(cc2c3B3c4ccc(-c6ccccc6)cc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1]

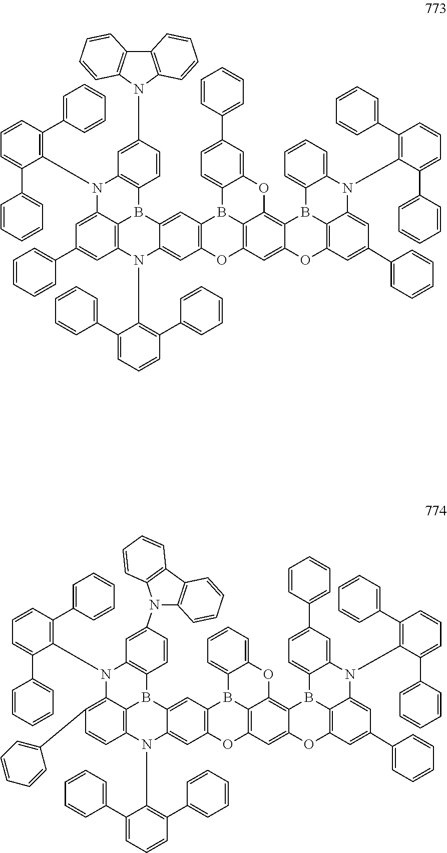 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)O5)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)N5c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2O3)N(c2c(-c3ccccc3)cccc2-c2ccccc2)c2ccc(-c3ccccc3)c3c2B5c2ccc(-n5c6ccccc6c6ccccc65)cc2N3c2c(-c3ccccc3)cccc2-c2ccccc2)O4)cc1]

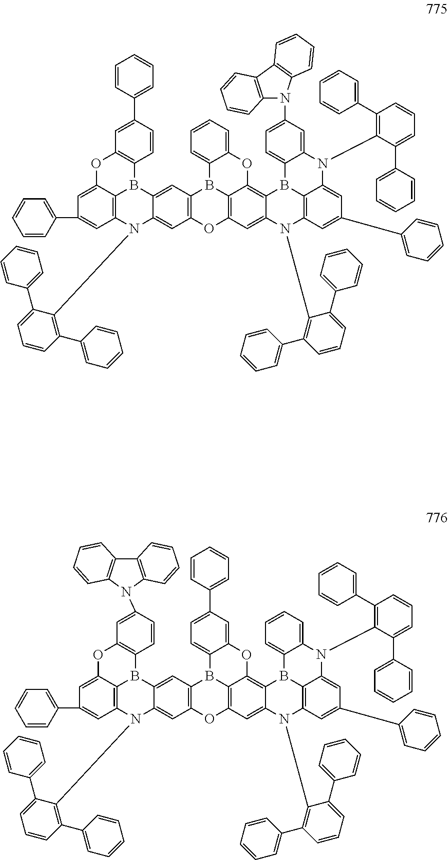 [SMILES: c1ccc(-c2ccc3c(c2)Oc2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3Oc3cc(-c4ccccc4)cc(c32)N5c2c(-c3ccccc3)cccc2-c2ccccc2)cc1]

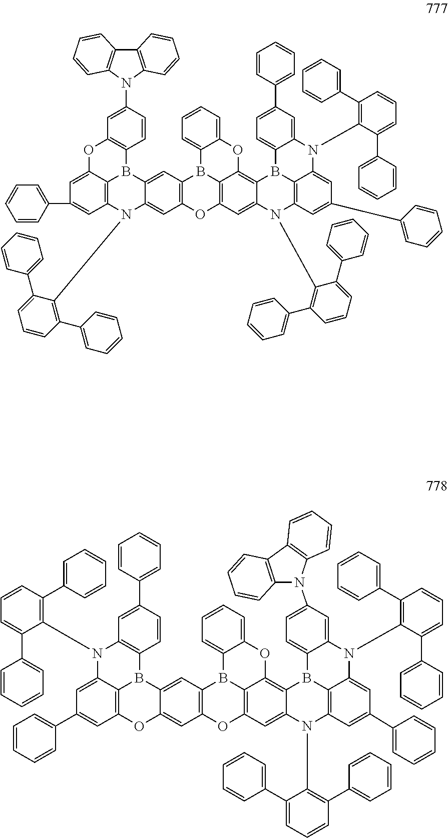 [SMILES: c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccc(-n5c6ccccc6c6ccccc65)cc2O3)N4c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2cc3c(cc2O4)Oc2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)N4c2c(-c3ccccc3)cccc2-c2ccccc2)cc1]

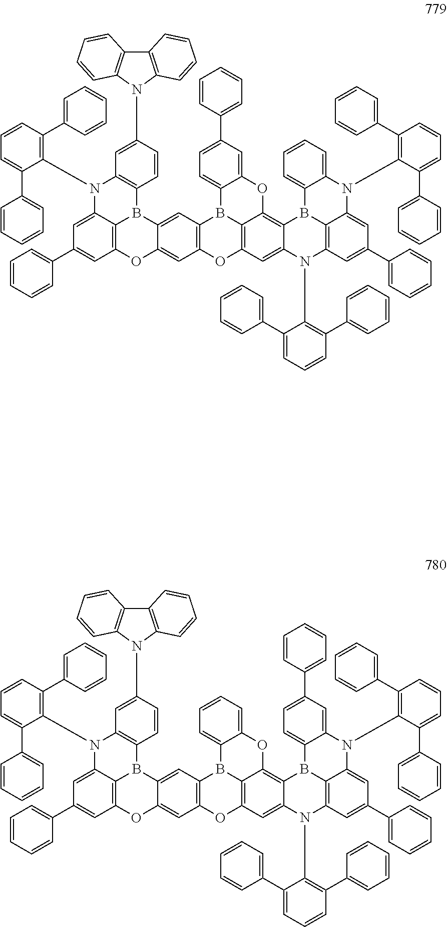 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)O5)cc1 ; c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2O3)Oc2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1]

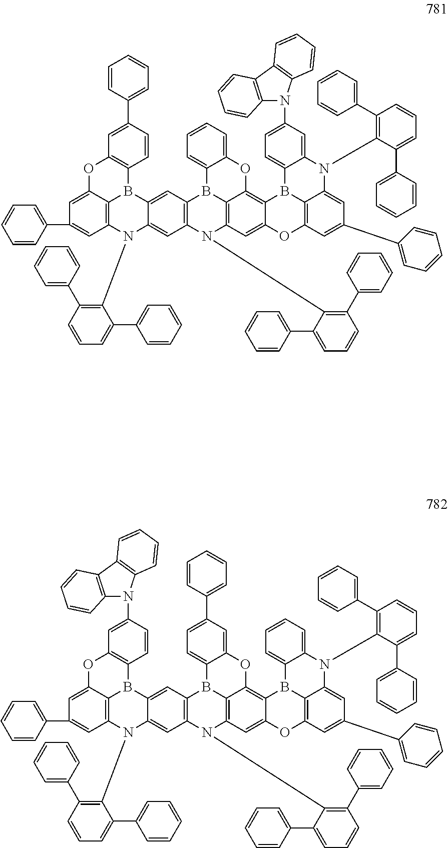 [SMILES: c1ccc(-c2ccc3c(c2)Oc2cc(-c4ccccc4)cc4c2B3c2cc3c(cc2N4c2c(-c4ccccc4)cccc2-c2ccccc2)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1 ; c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccc(-n3c6ccccc6c6ccccc63)cc2O5)Oc2cc(-c3ccccc3)cc3c2B4c2ccccc2N3c2c(-c3ccccc3)cccc2-c2ccccc2)cc1]

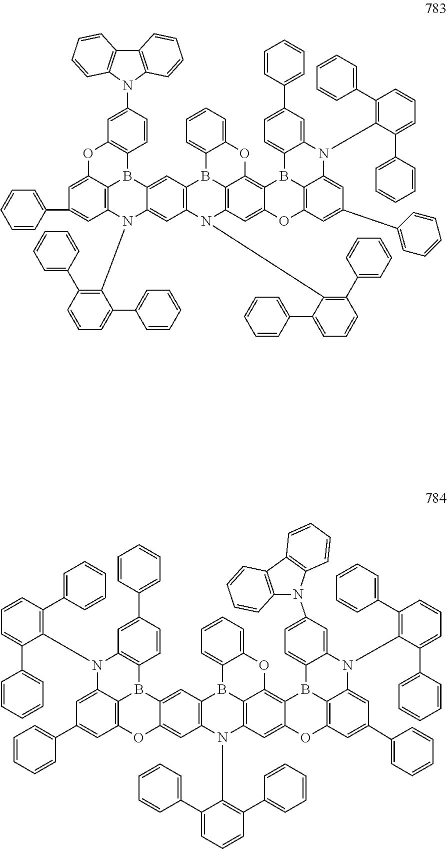 [SMILES: c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2cc(-c3ccccc3)cc3c2B5c2ccc(-n5c6ccccc6c6ccccc65)cc2O3)O4)cc1 ; c1ccc(-c2ccc3c(c2)N(c2c(-c4ccccc4)cccc2-c2ccccc2)c2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1]

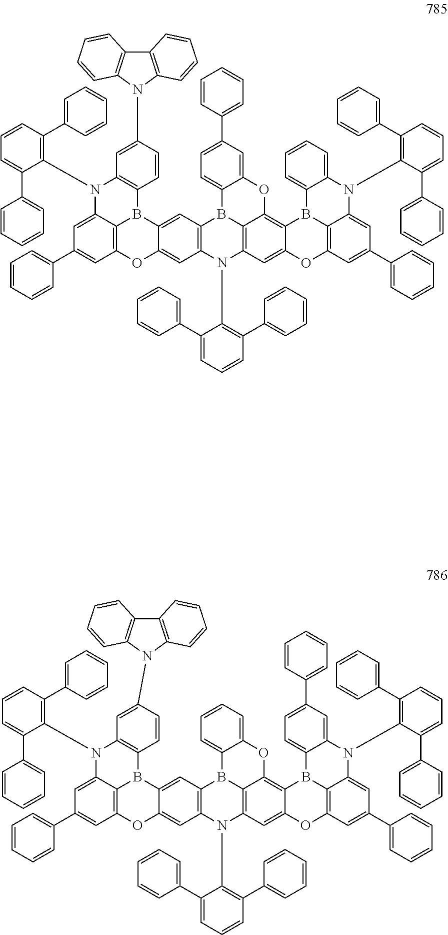 [SMILES: c1ccc(-c2ccc3c(c2)Oc2c4c(cc5c2B3c2cc3c(cc2N5c2c(-c5ccccc5)cccc2-c2ccccc2)Oc2cc(-c5ccccc5)cc5c2B3c2ccc(-n3c6ccccc6c6ccccc63)cc2N5c2c(-c3ccccc3)cccc2-c2ccccc2)Oc2cc(-c3ccccc3)cc3c2B4c2ccccc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2N3c2c(-c3ccccc3)cccc2-c2ccccc2)O4)cc1]

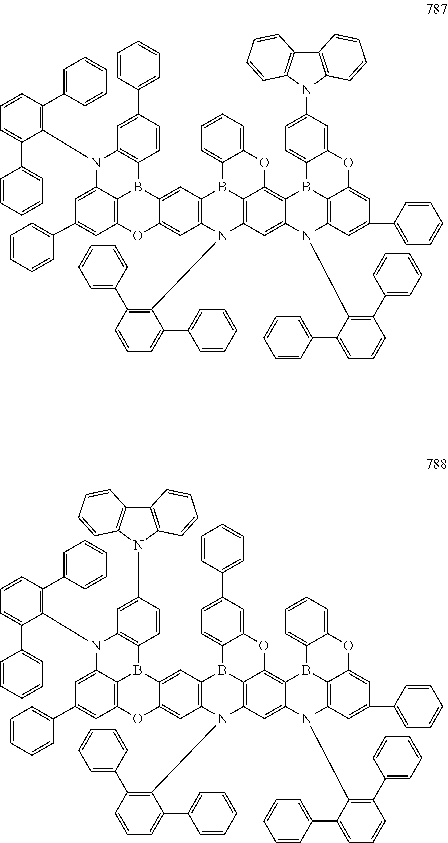 [SMILES: c1ccc(-c2ccc3c(c2)N(c2c(-c4ccccc4)cccc2-c2ccccc2)c2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3N(c3c(-c4ccccc4)cccc3-c3ccccc3)c3cc(-c4ccccc4)cc(c32)O5)cc1]

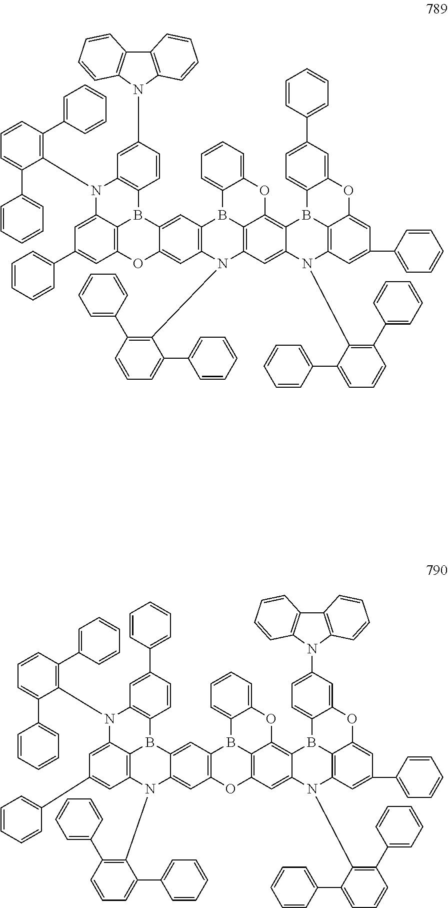 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1]

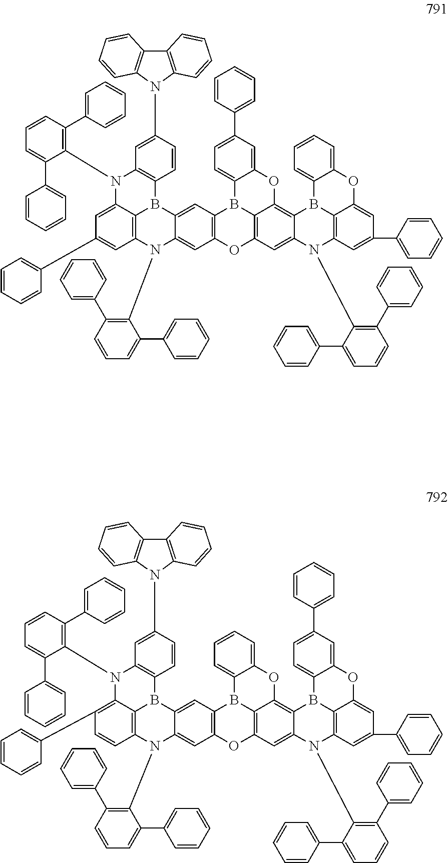 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)N5c2c(-c3ccccc3)cccc2-c2ccccc2)cc1 ; c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2ccc(-c3ccccc3)c3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1]

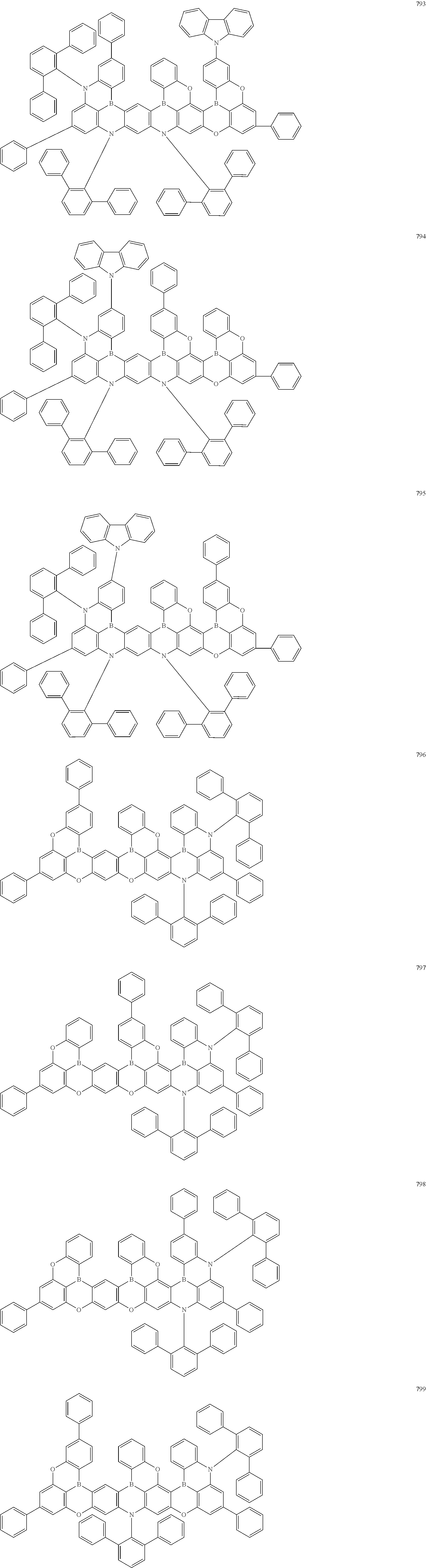

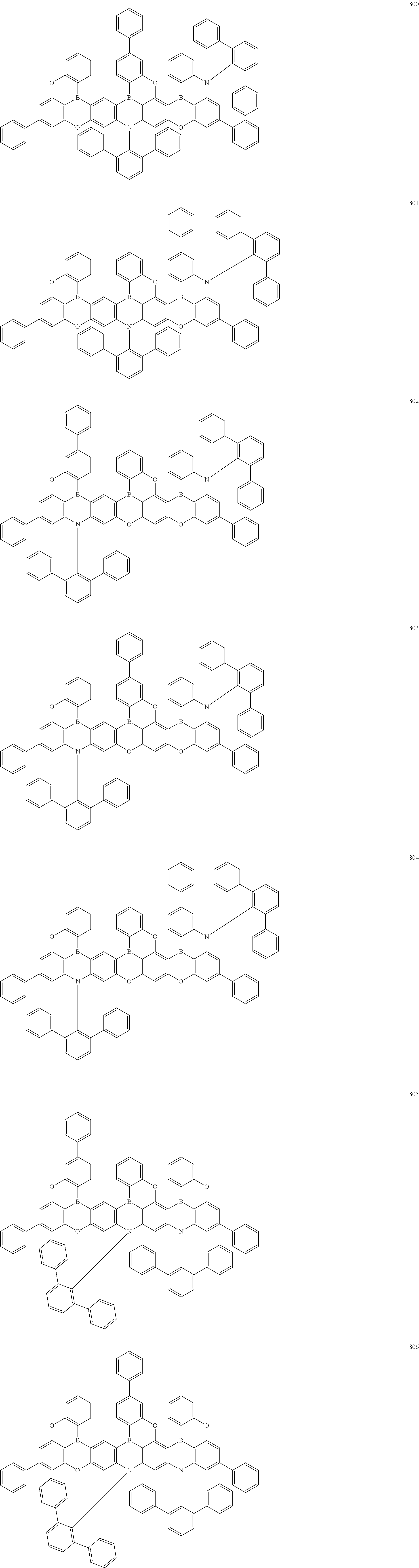

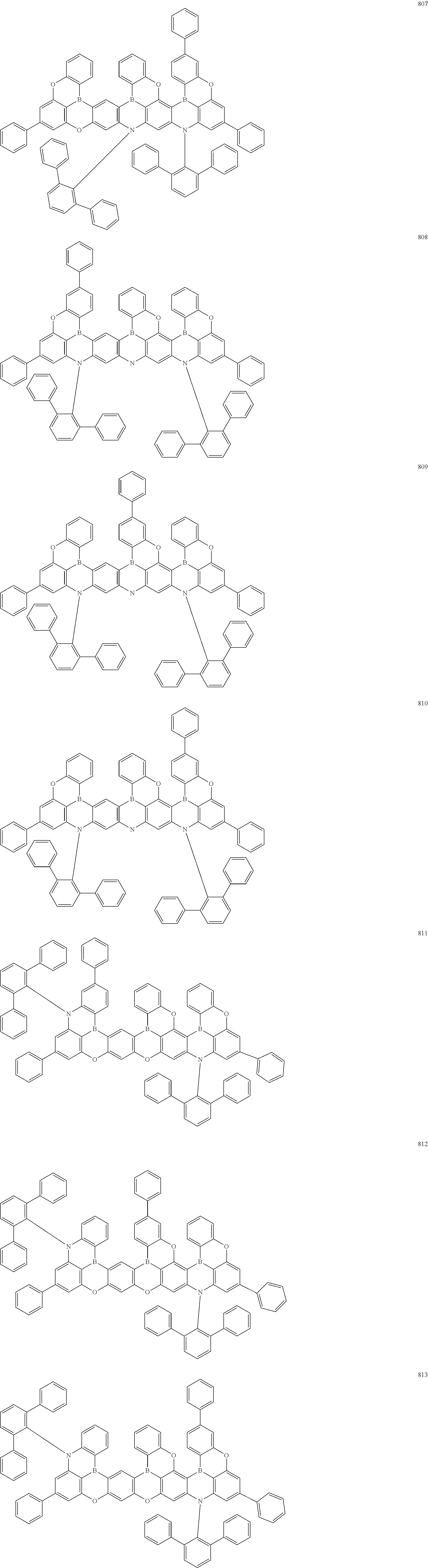

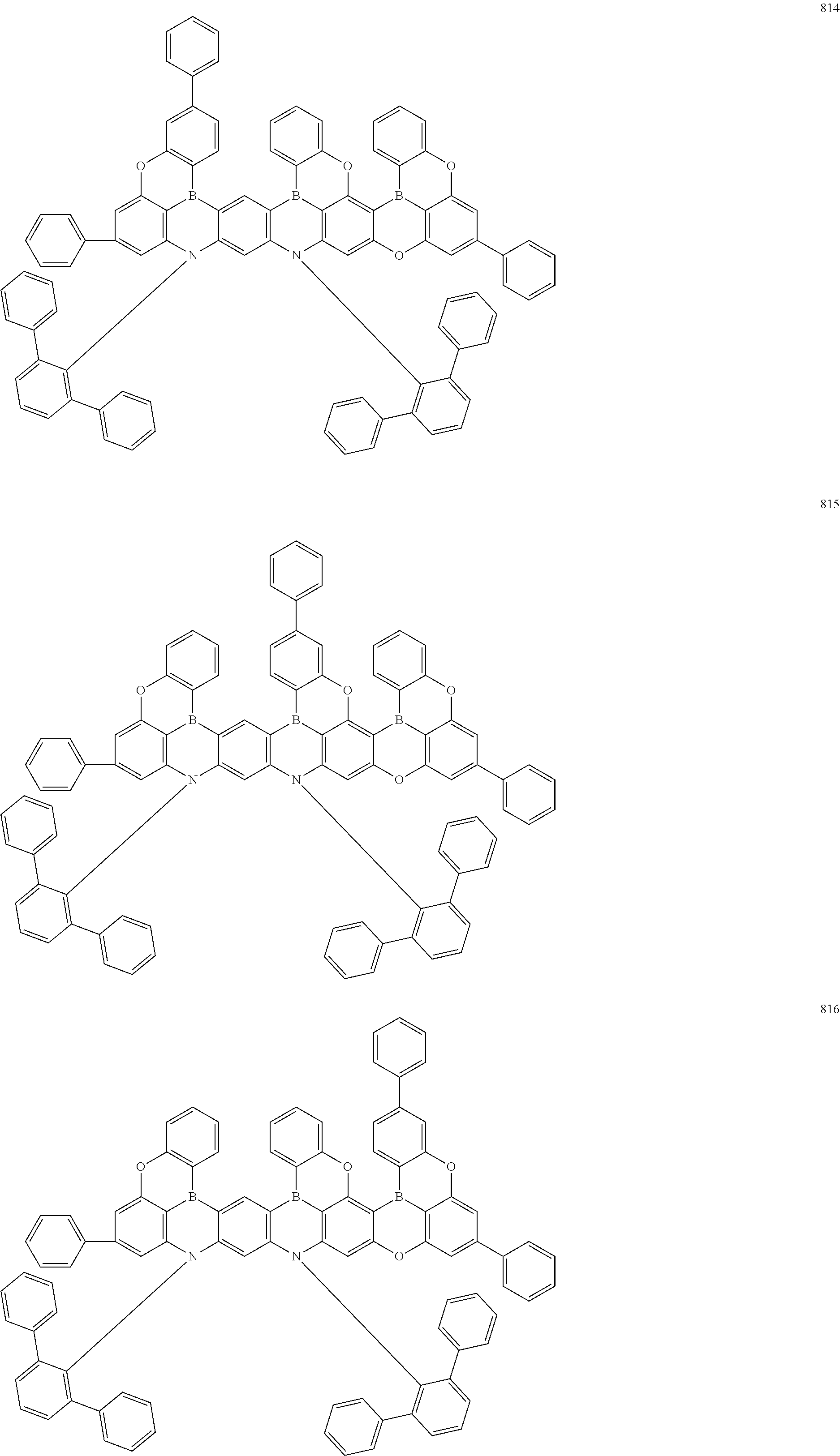

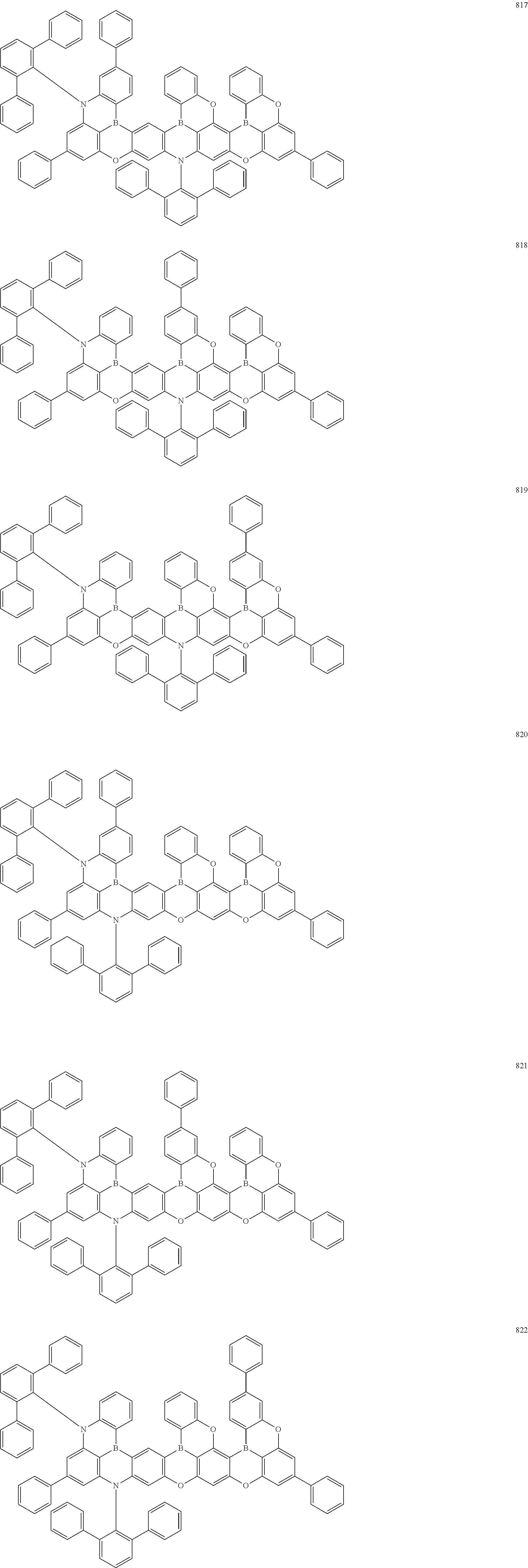

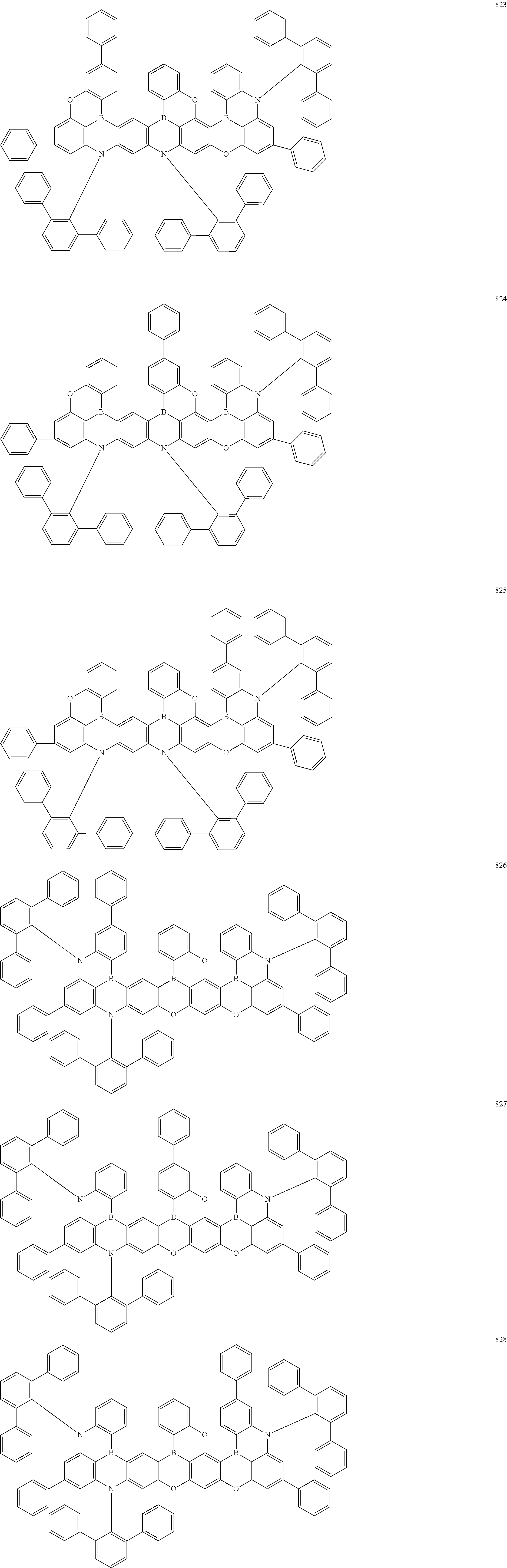

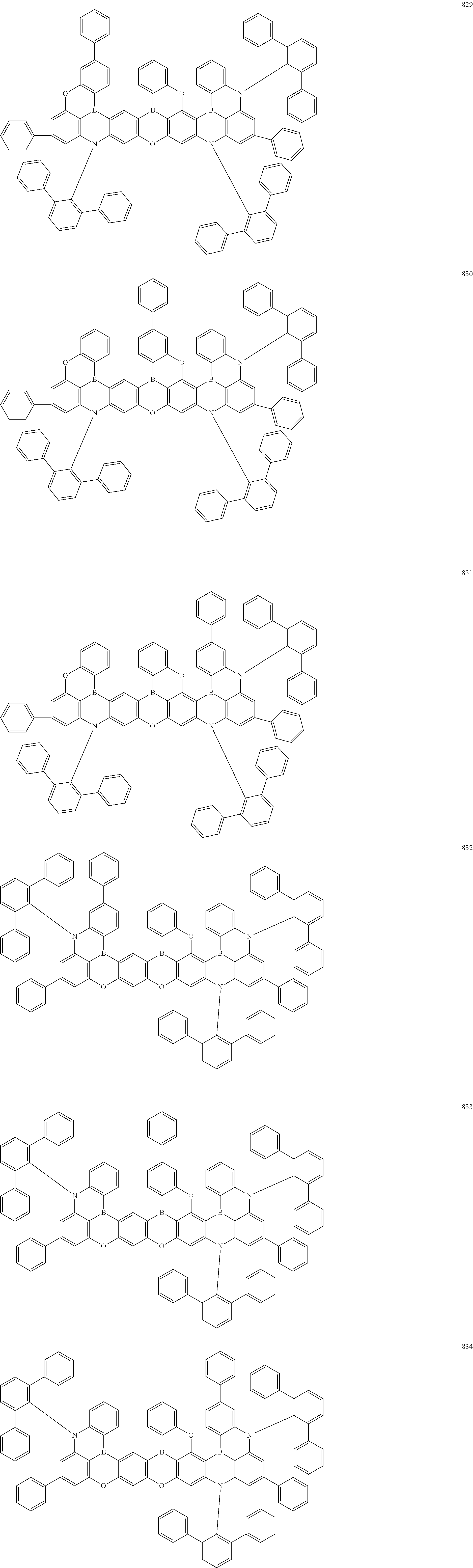

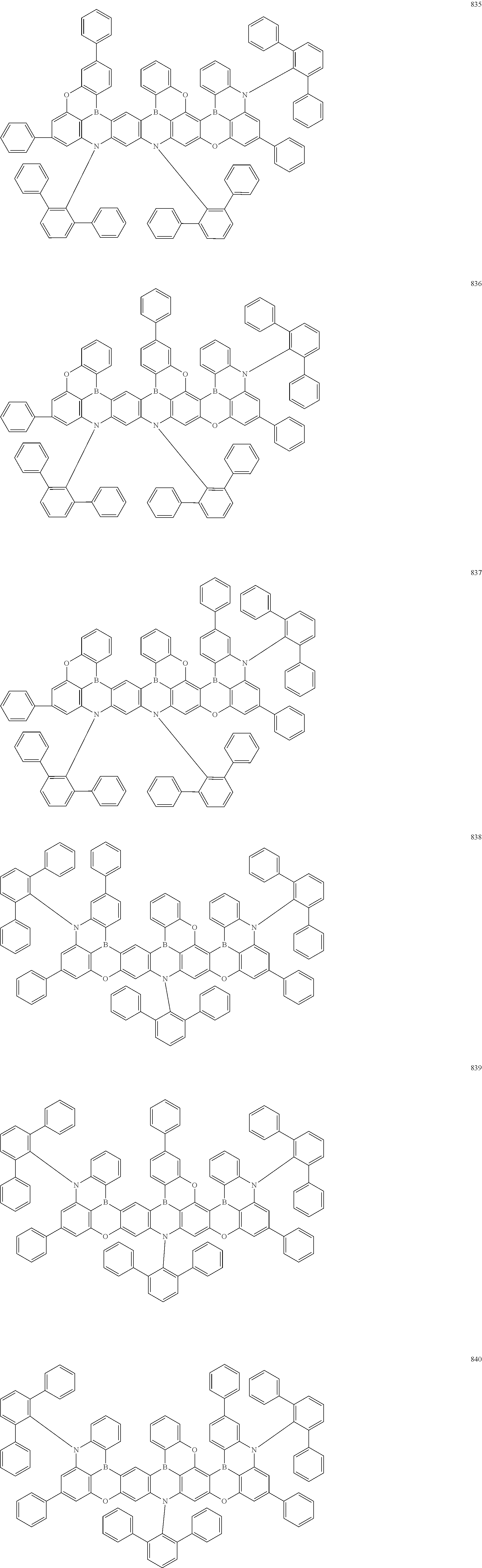

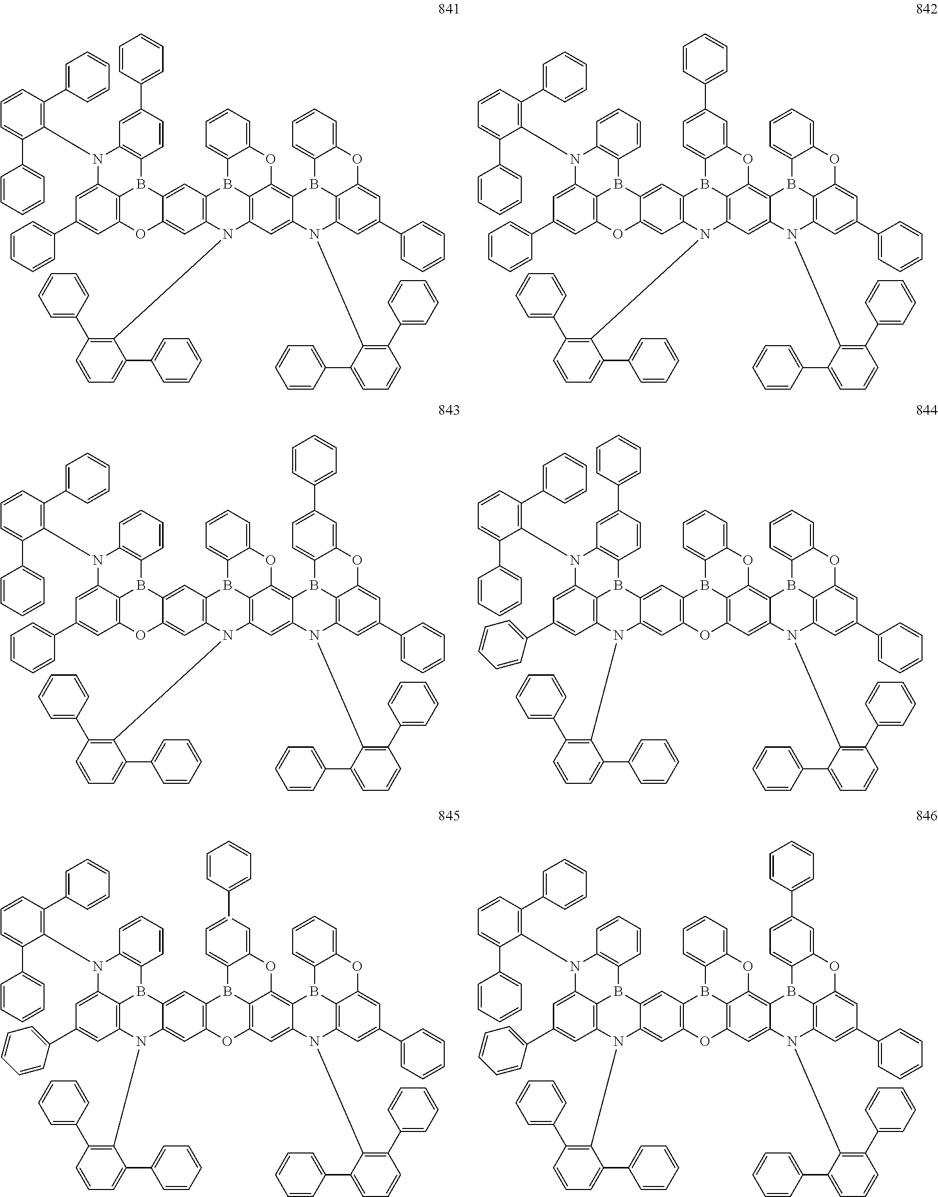

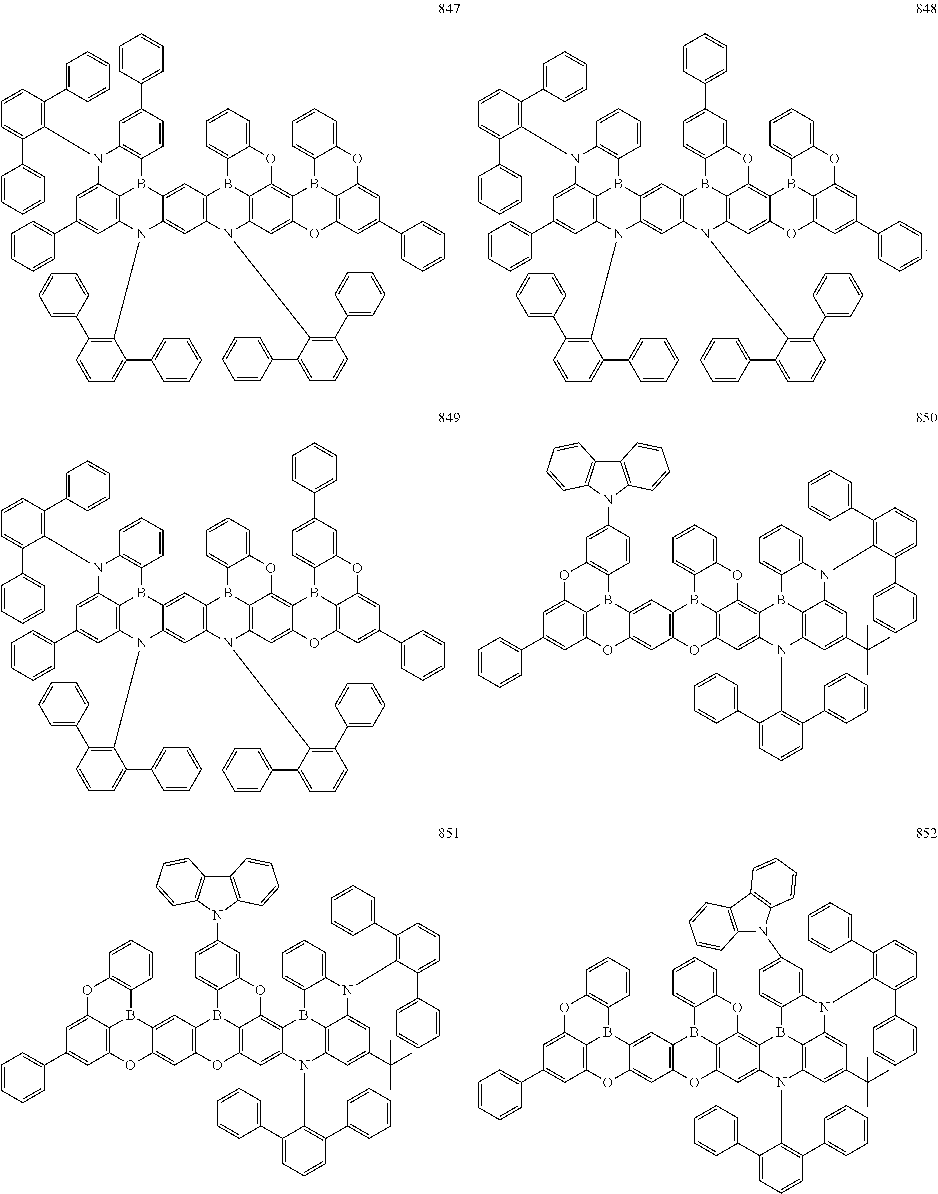

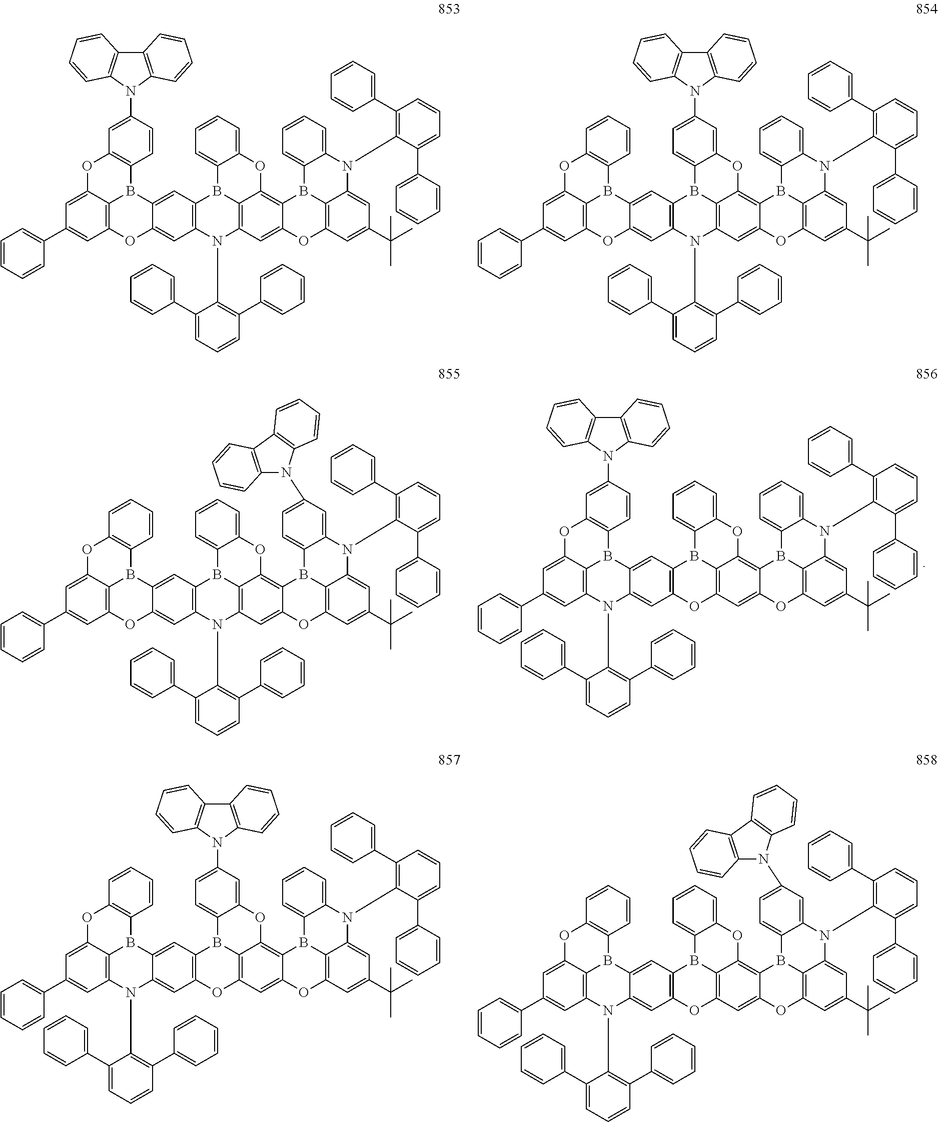

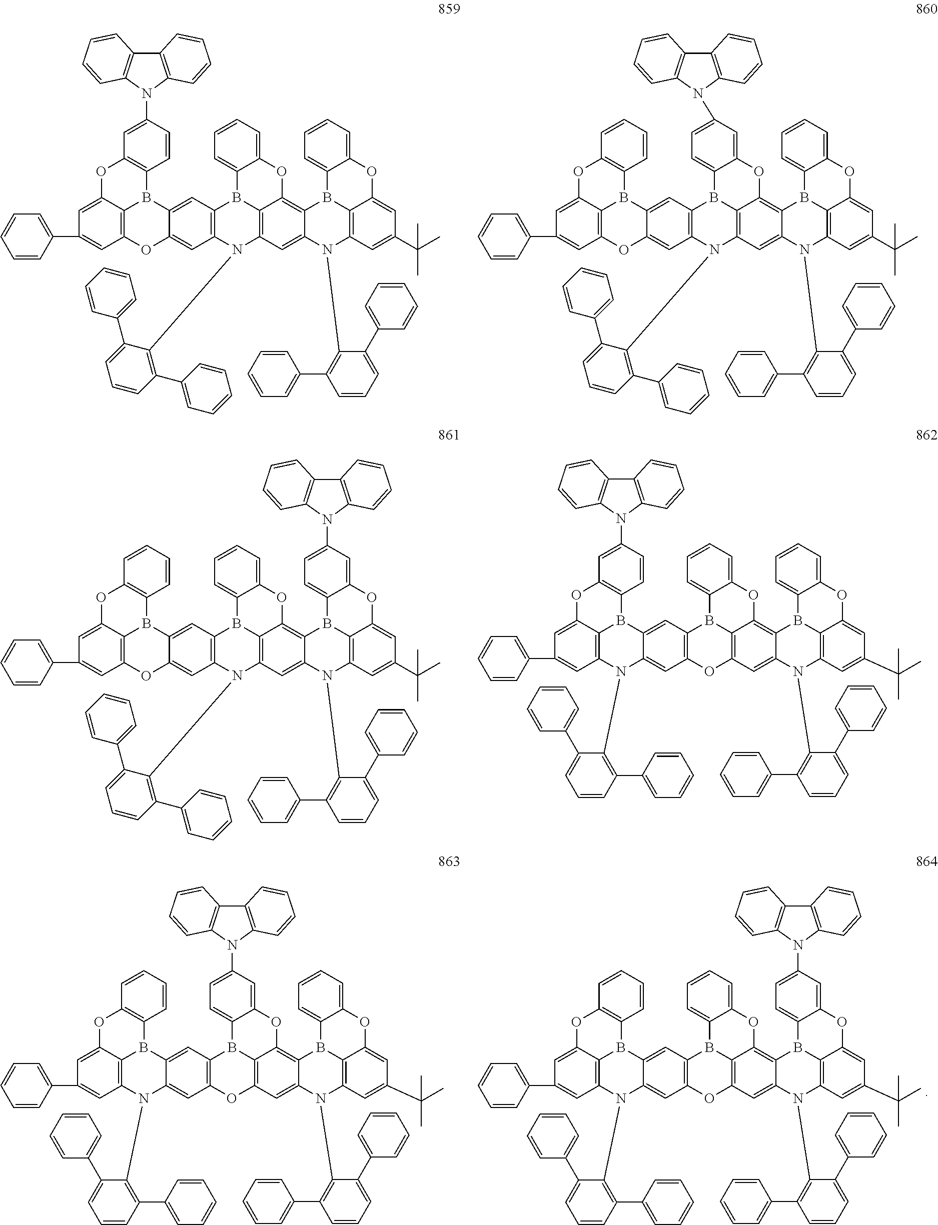

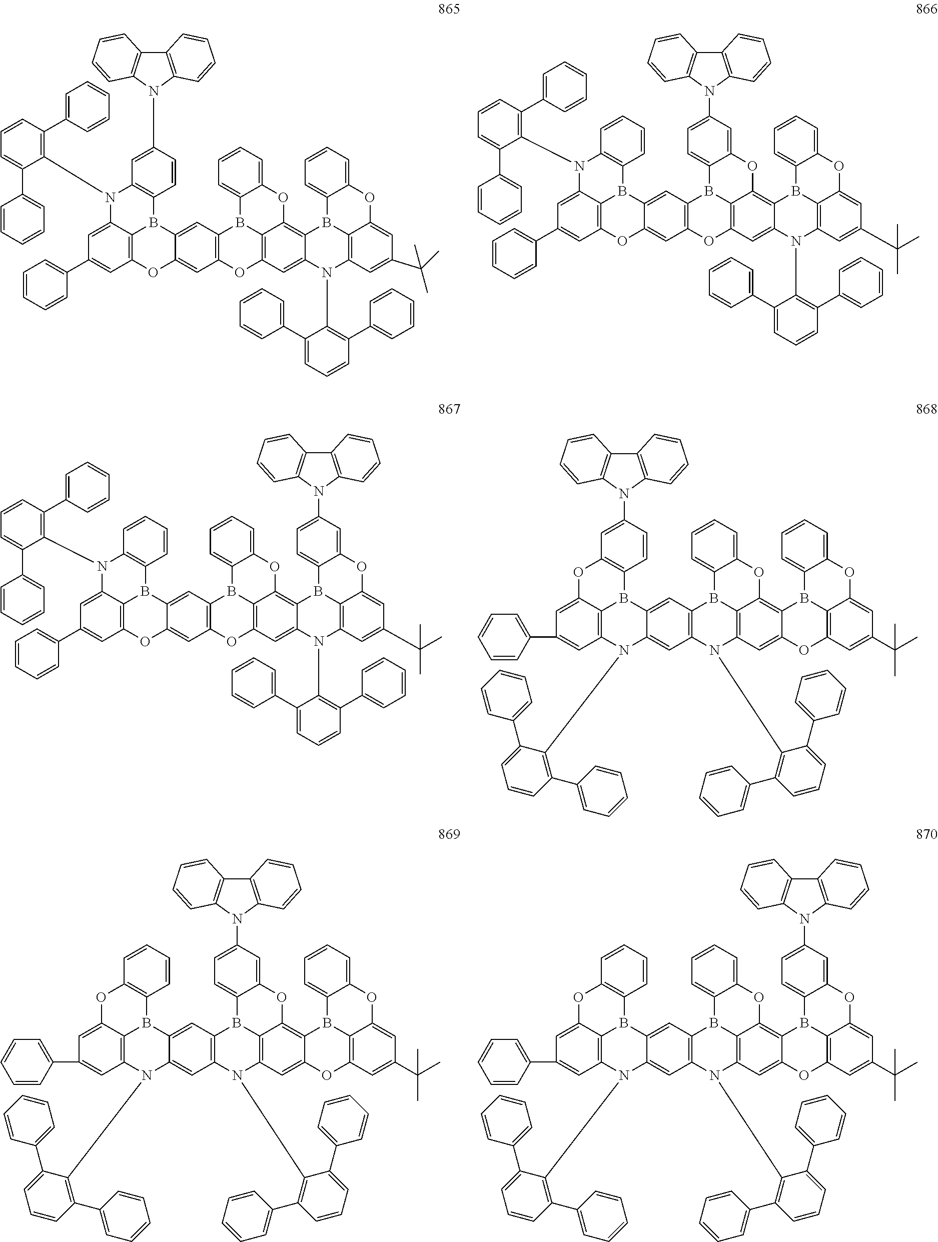

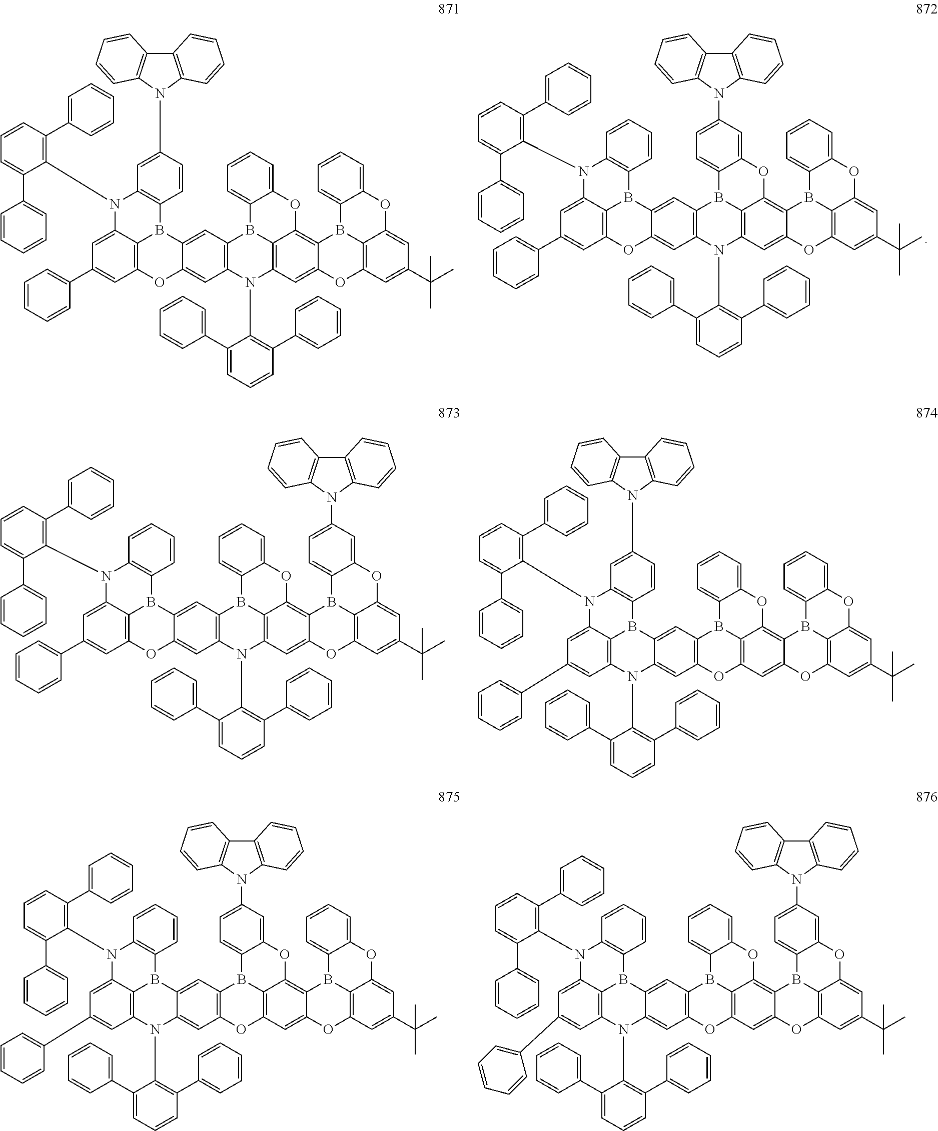

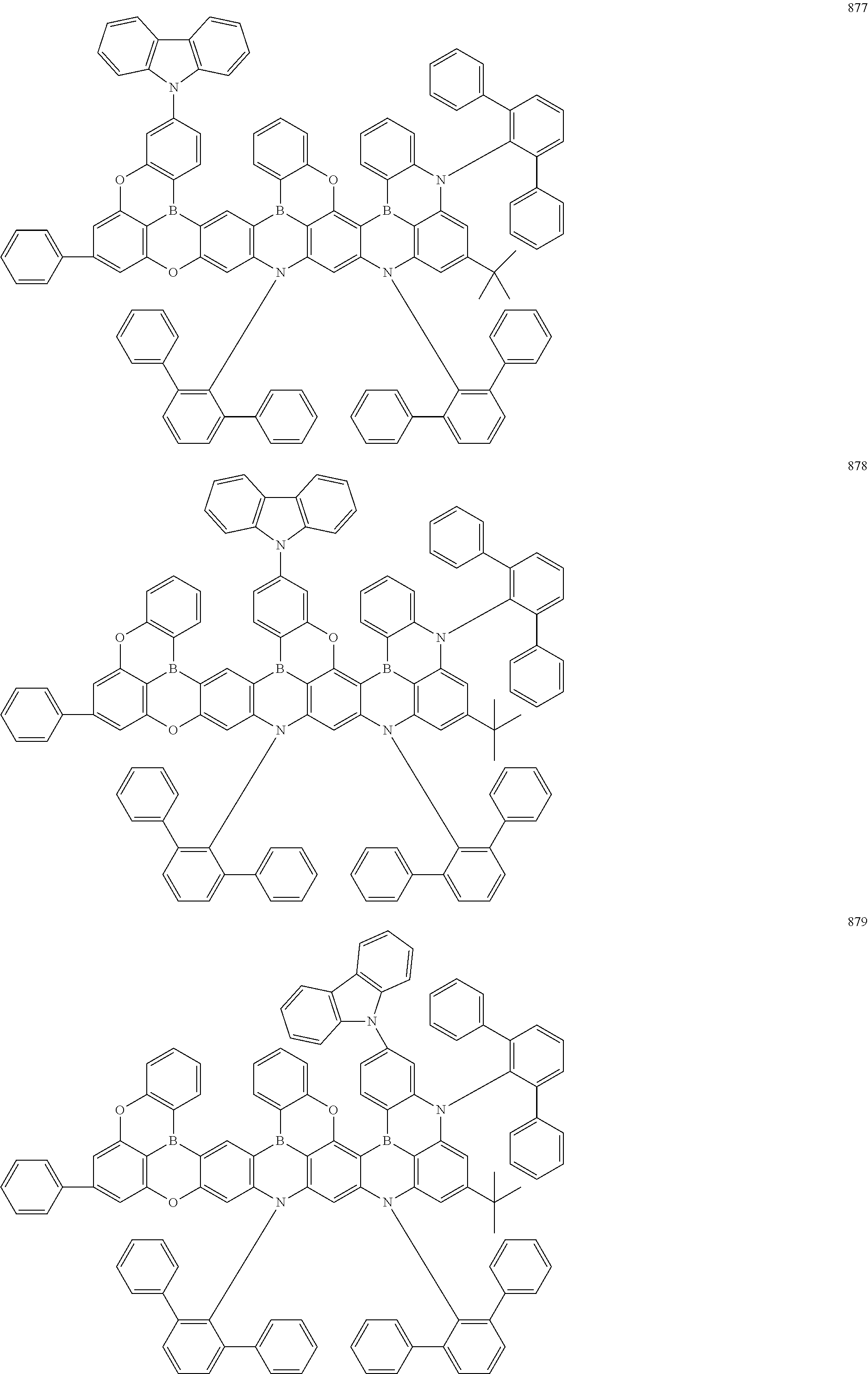

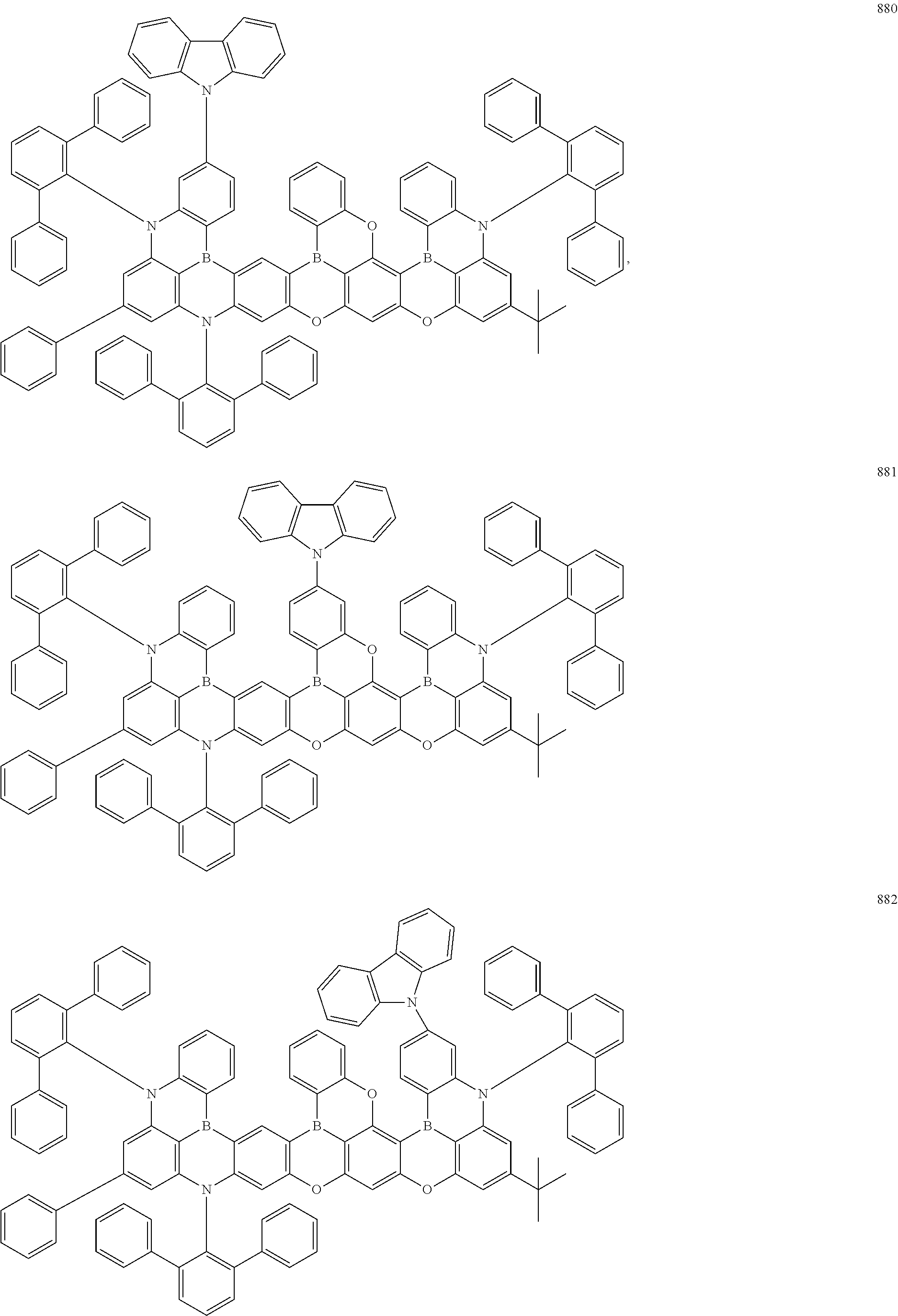

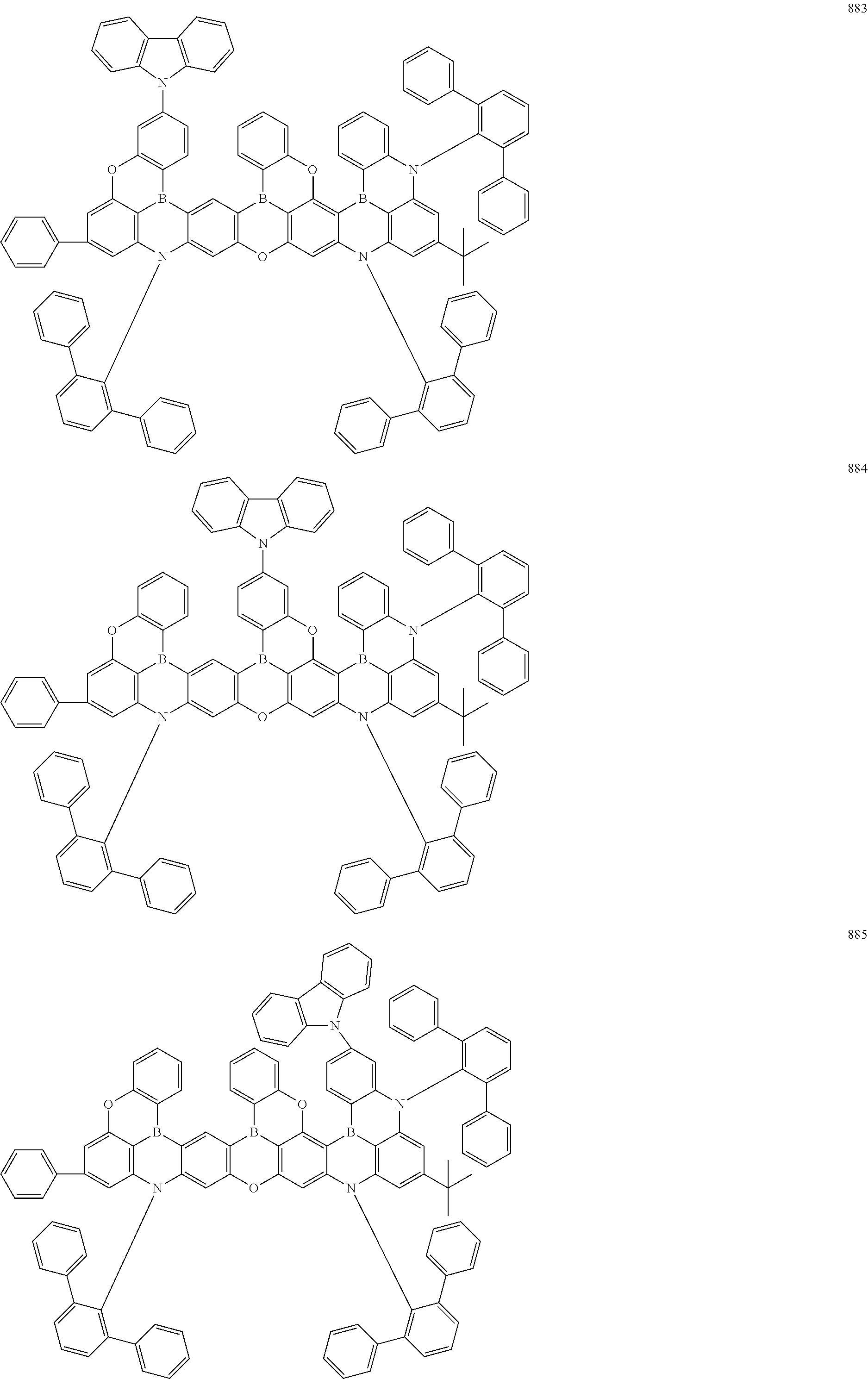

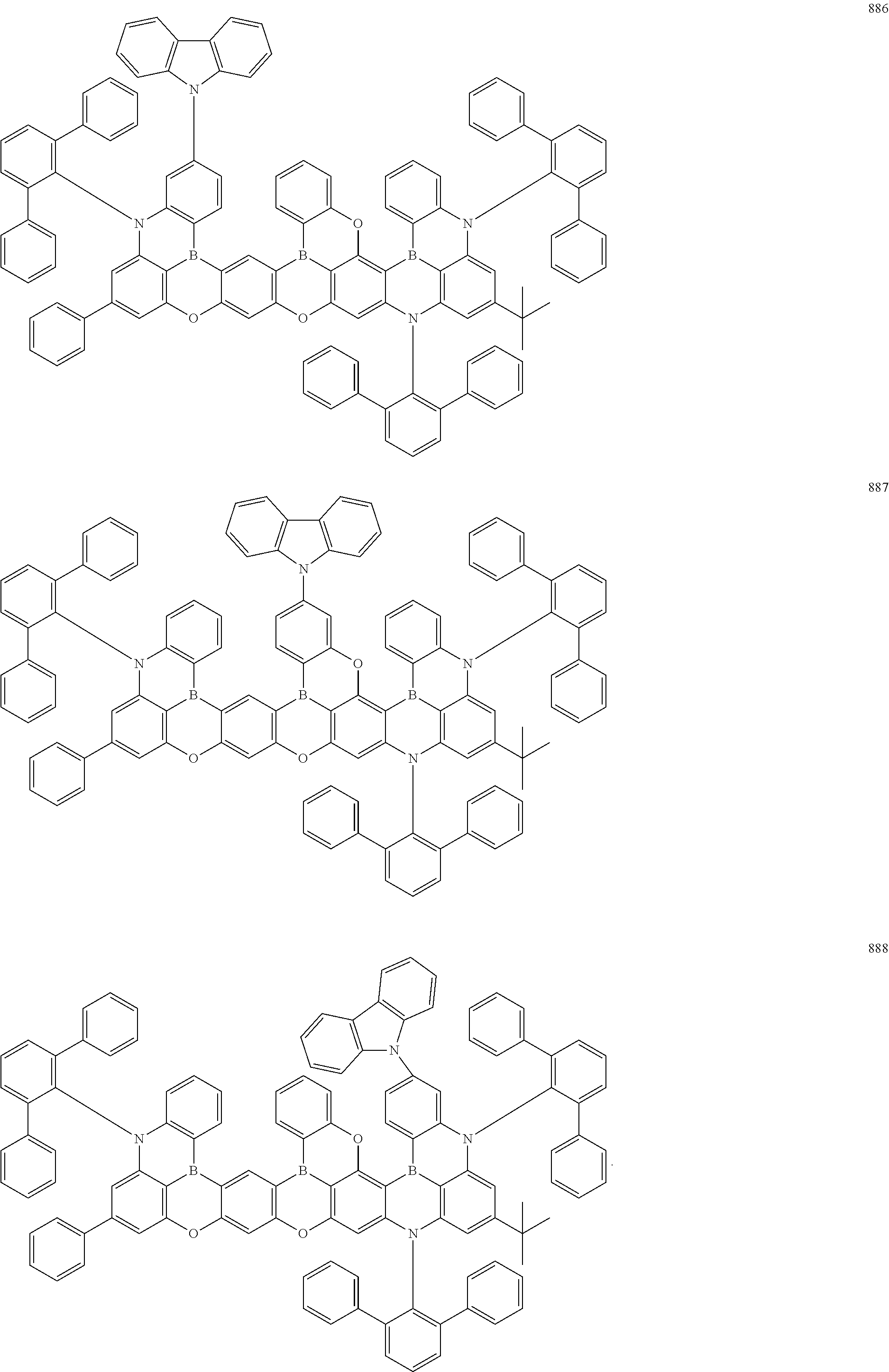

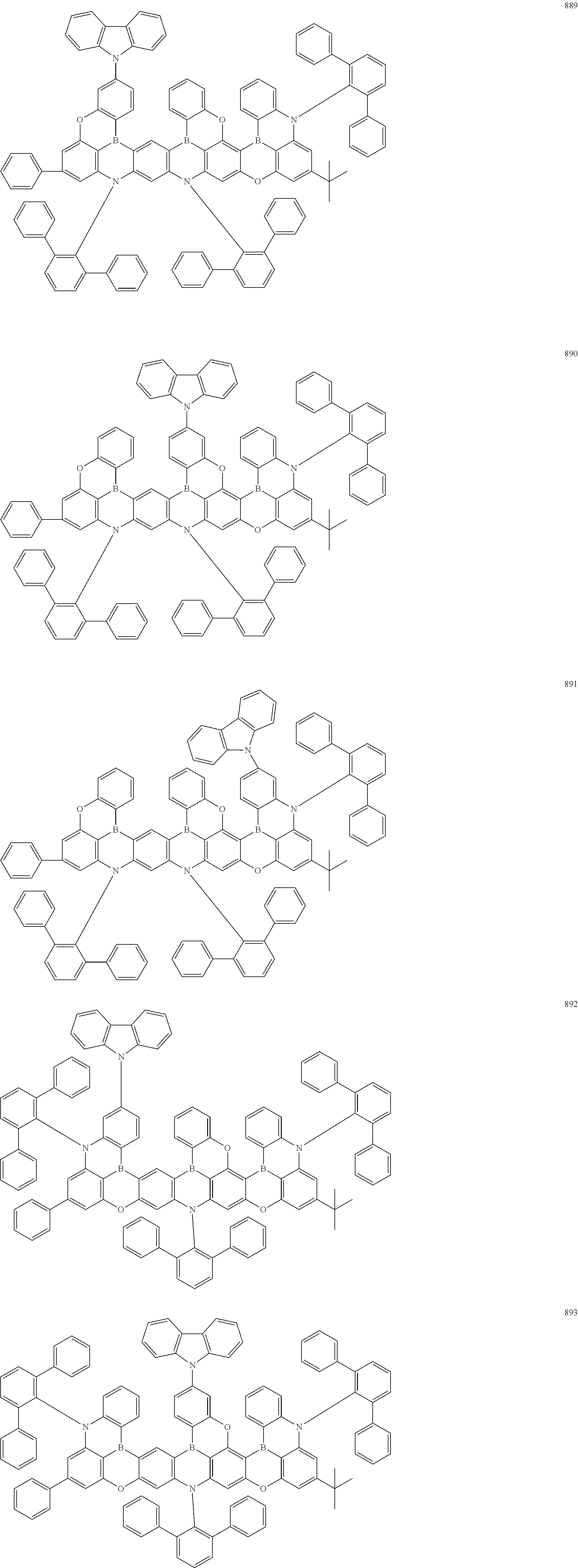

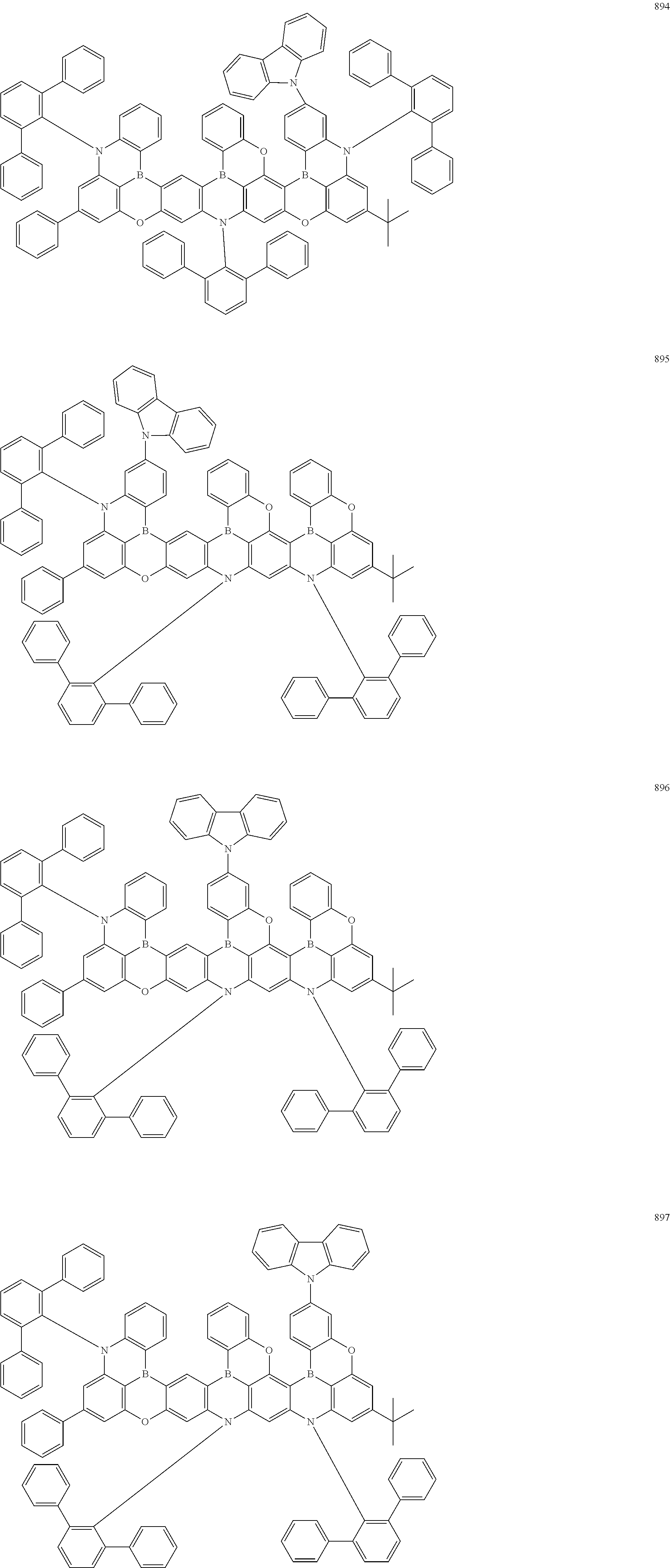

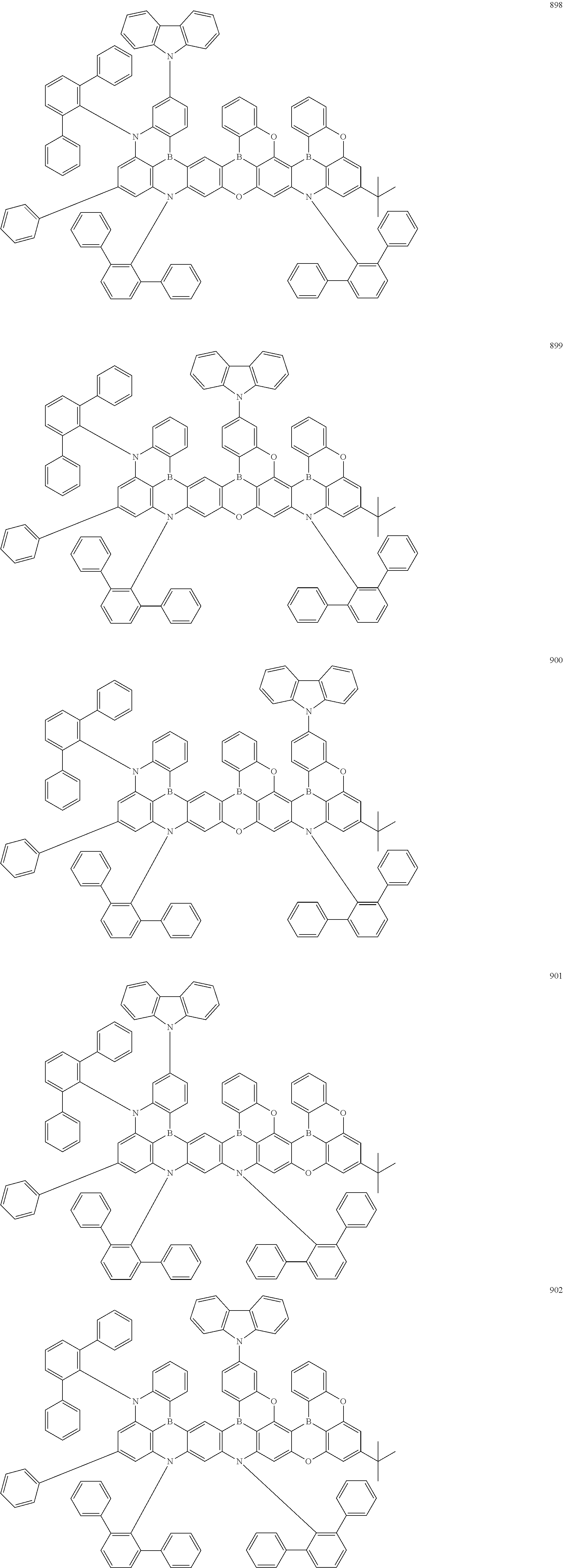

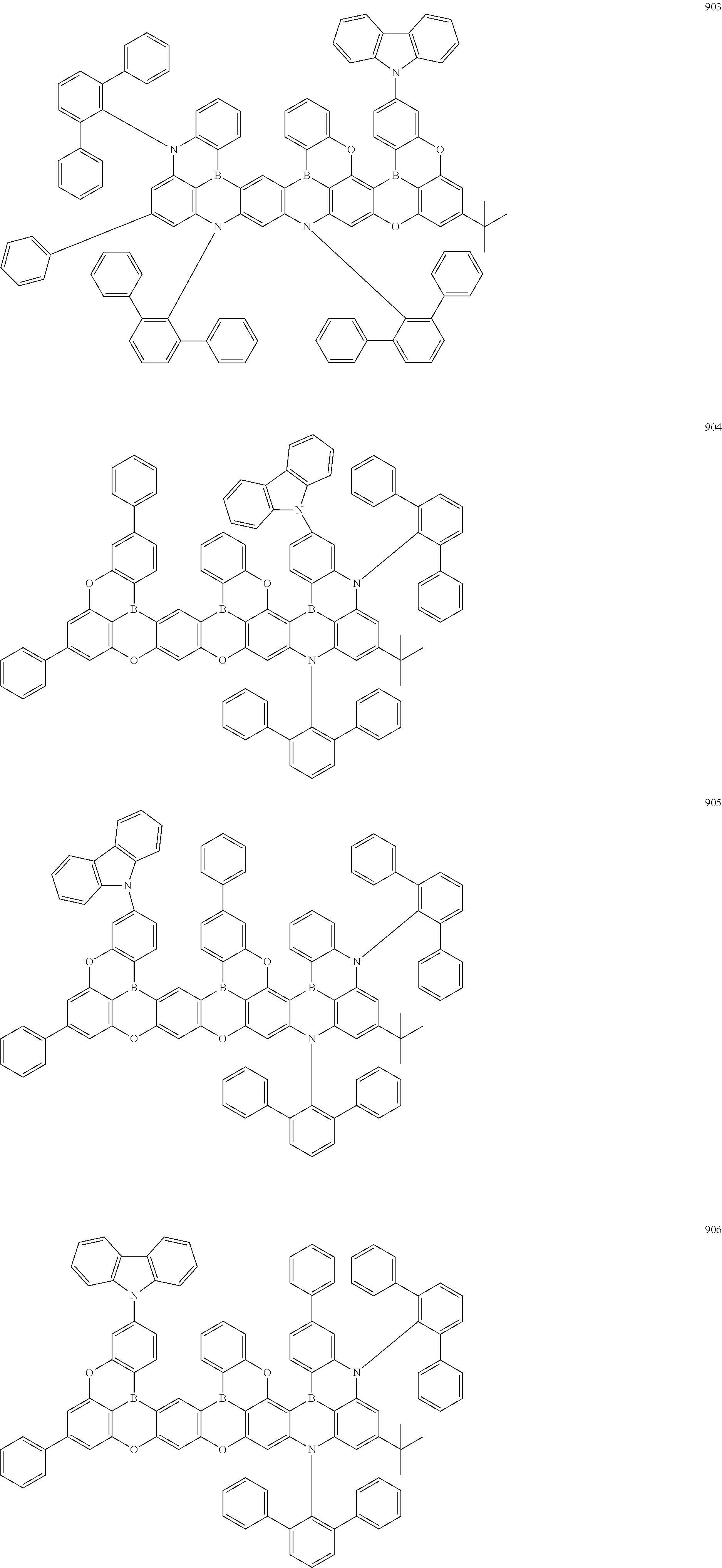

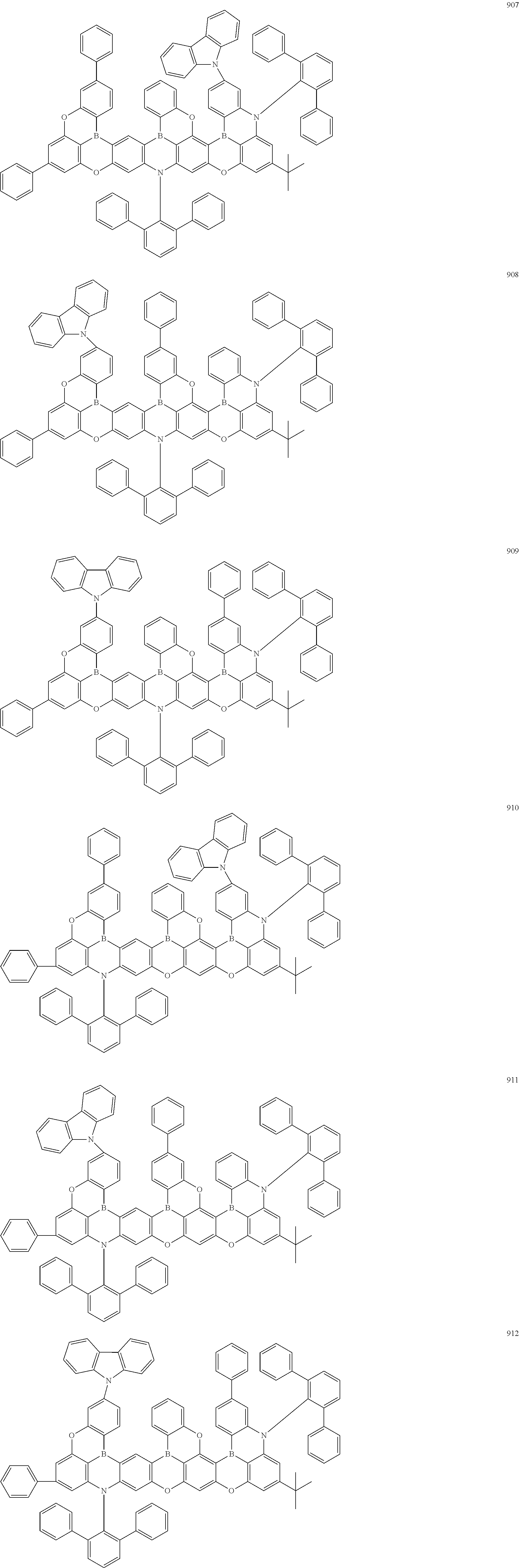

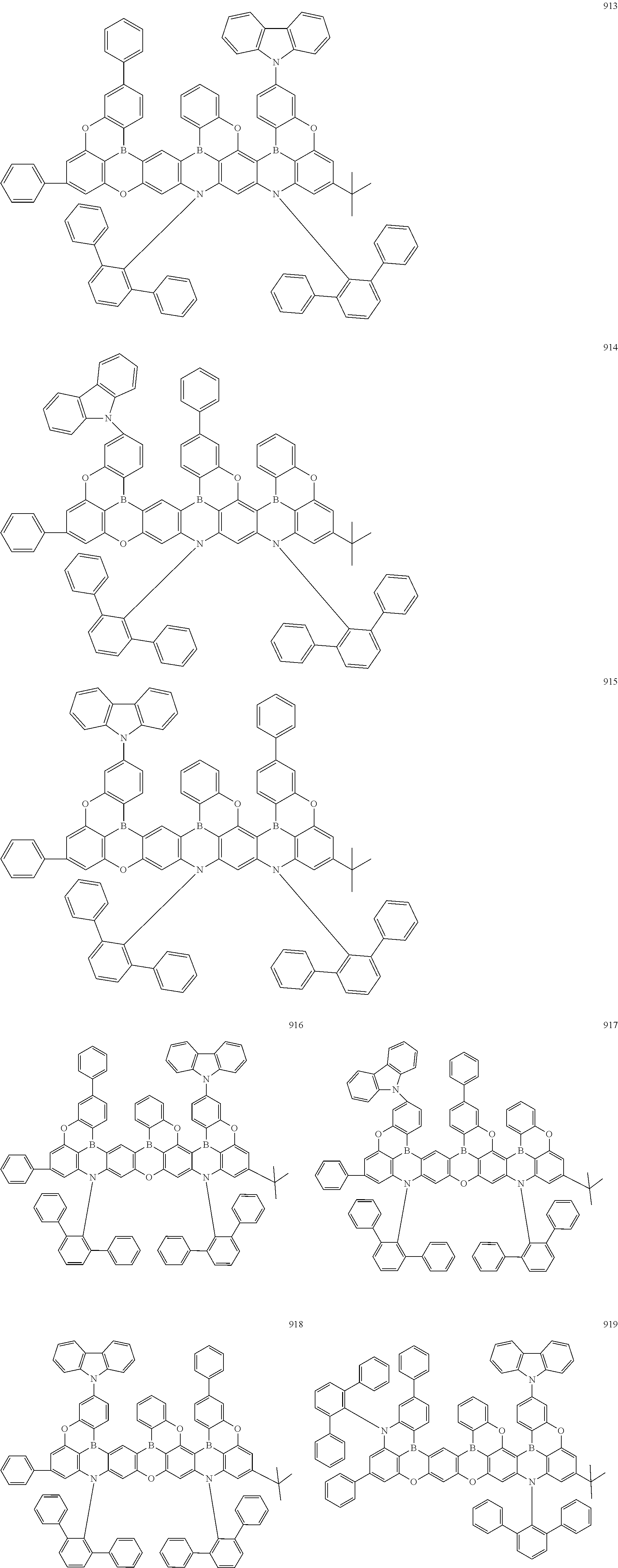

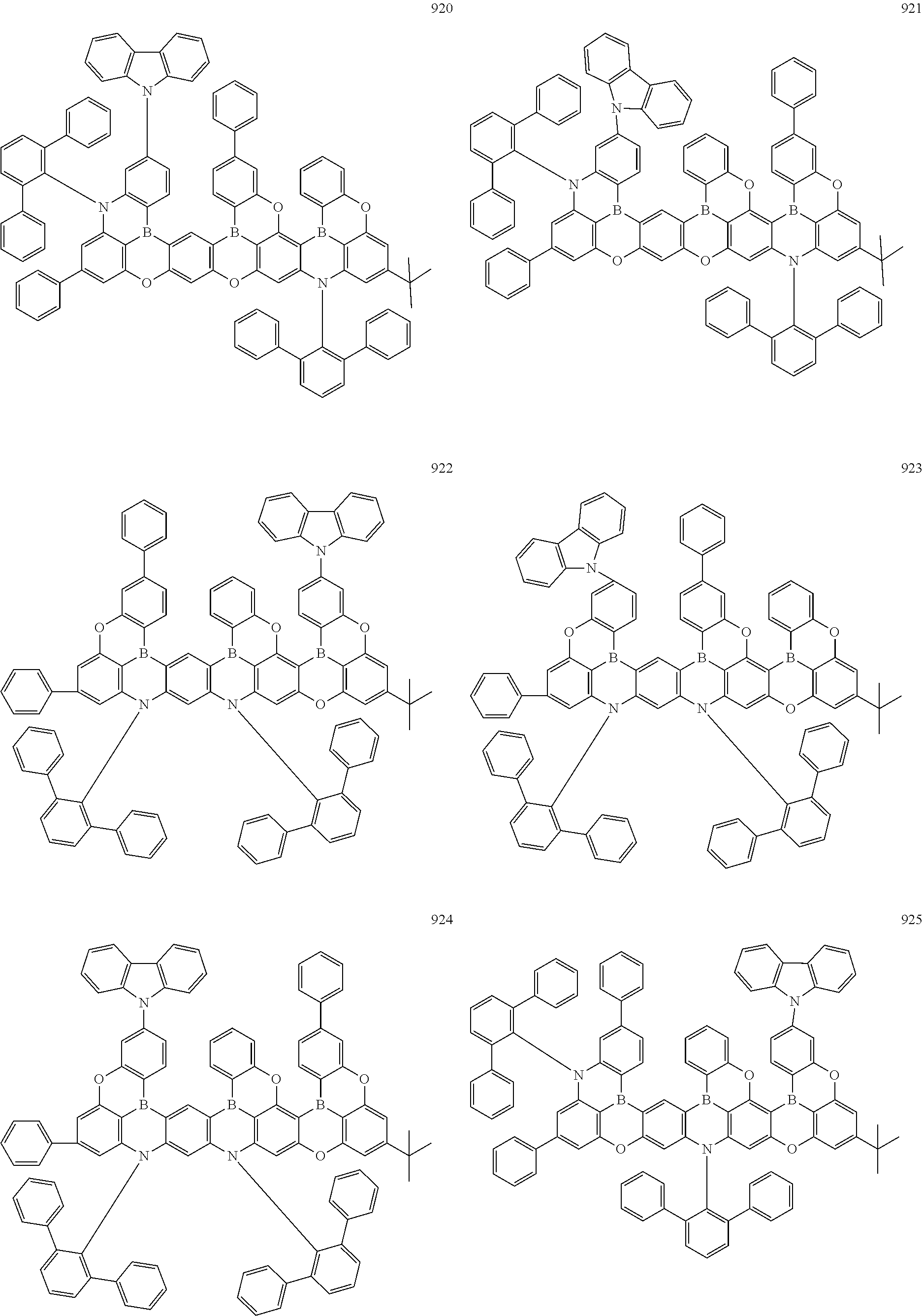

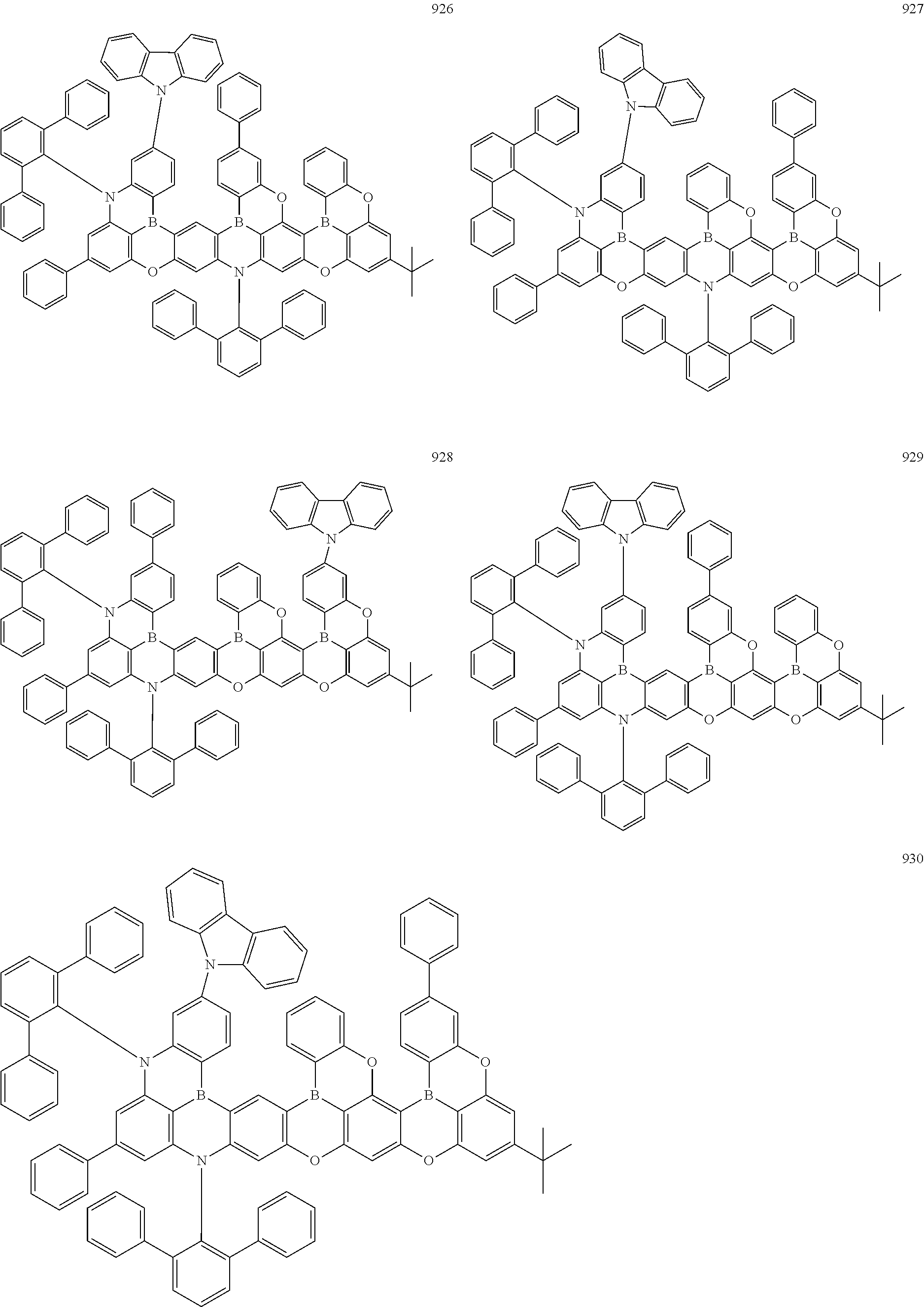

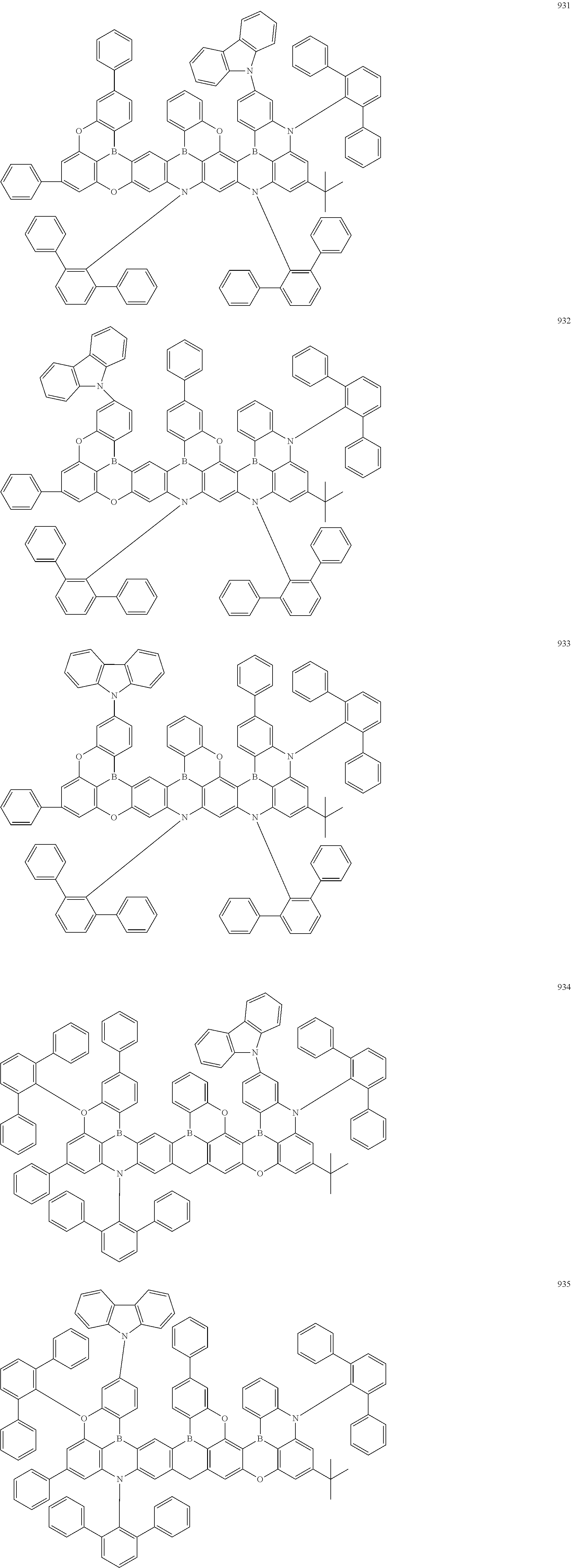

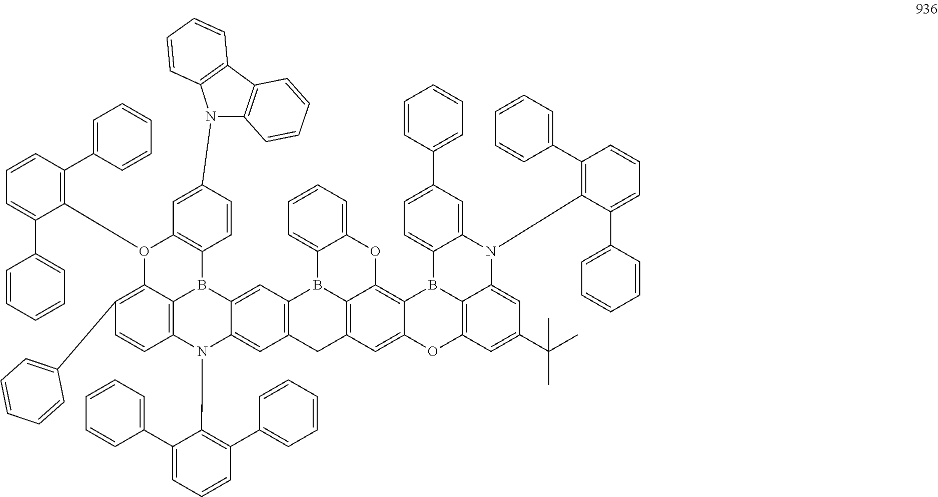

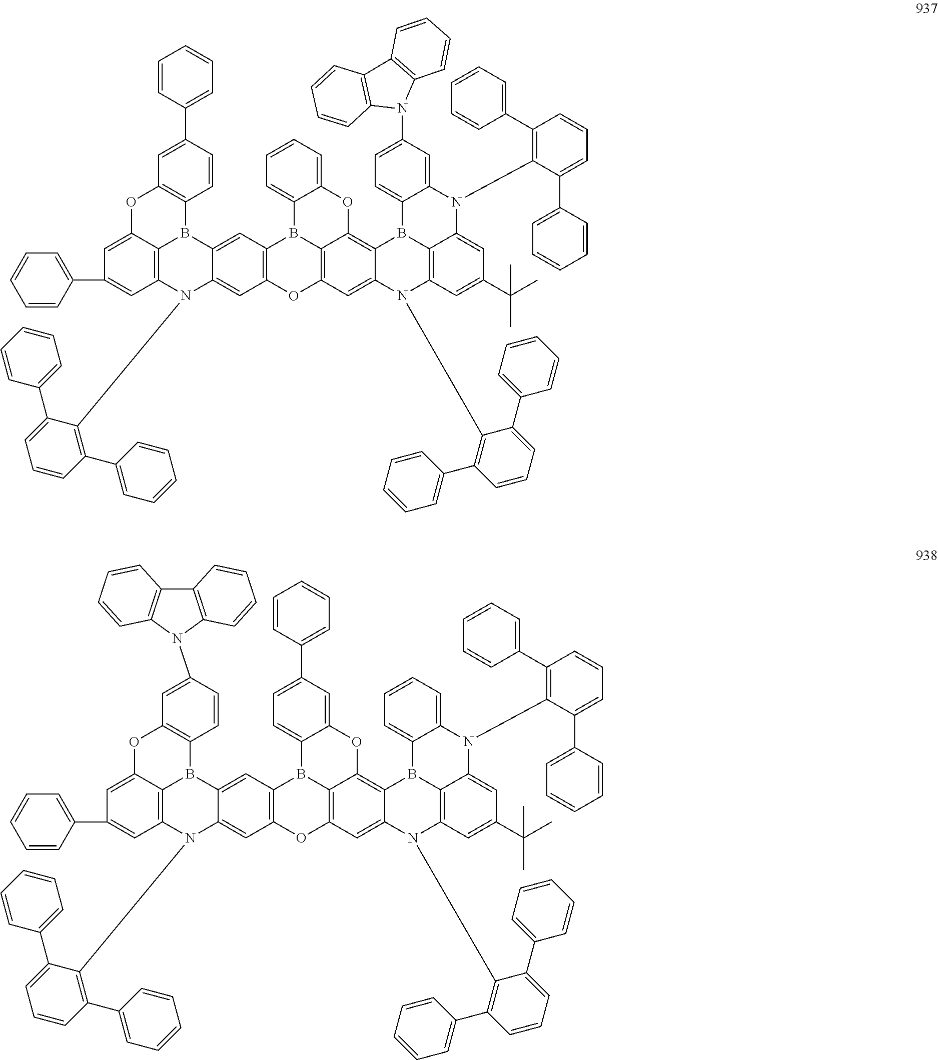 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccc(-c2ccccc2)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3]

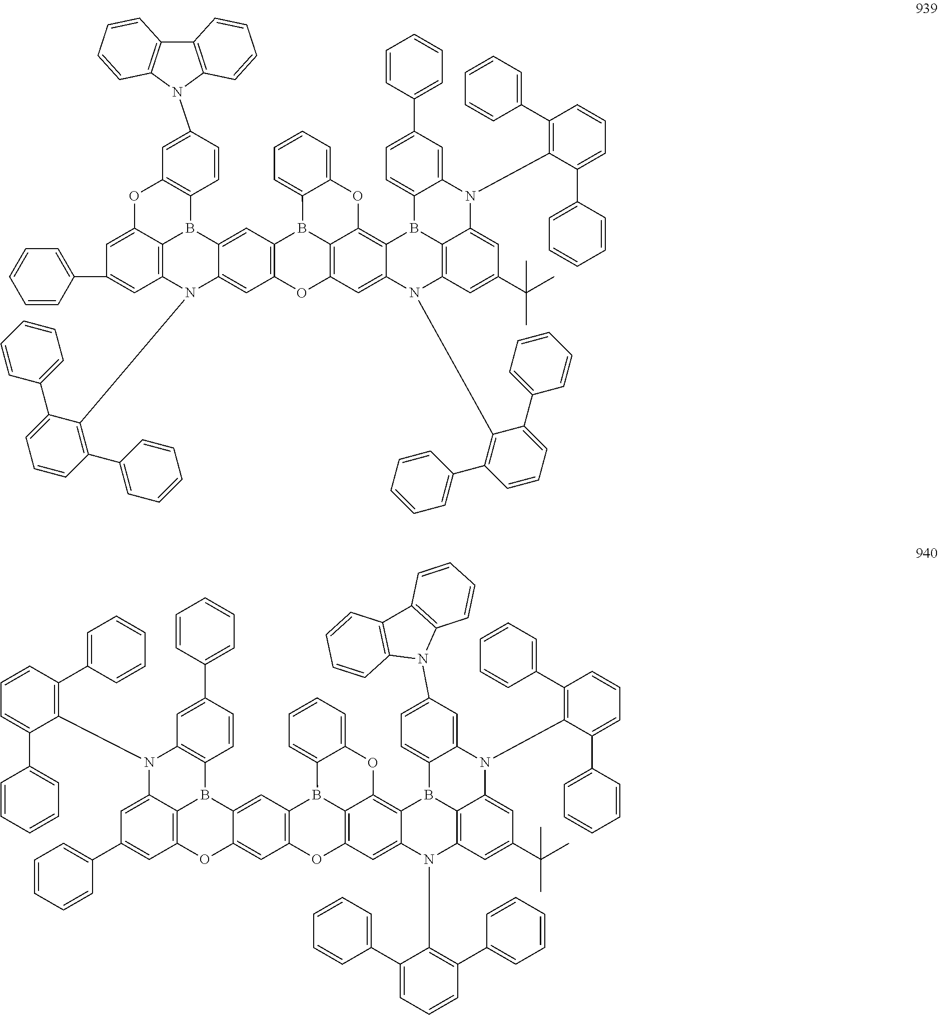 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)Oc1cc(-c3ccccc3)cc3c1B2c1ccc(-c2ccccc2)cc1N3c1c(-c2ccccc2)cccc1-c1ccccc1]

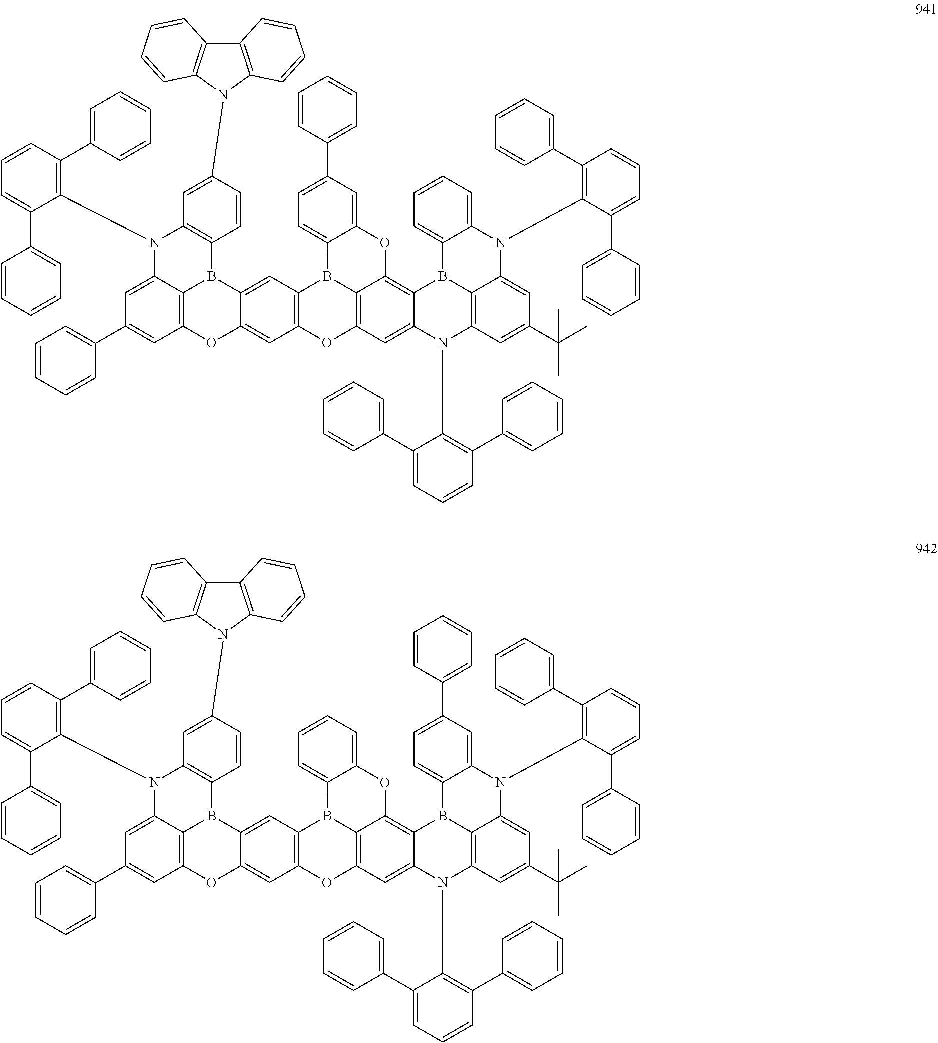 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1]

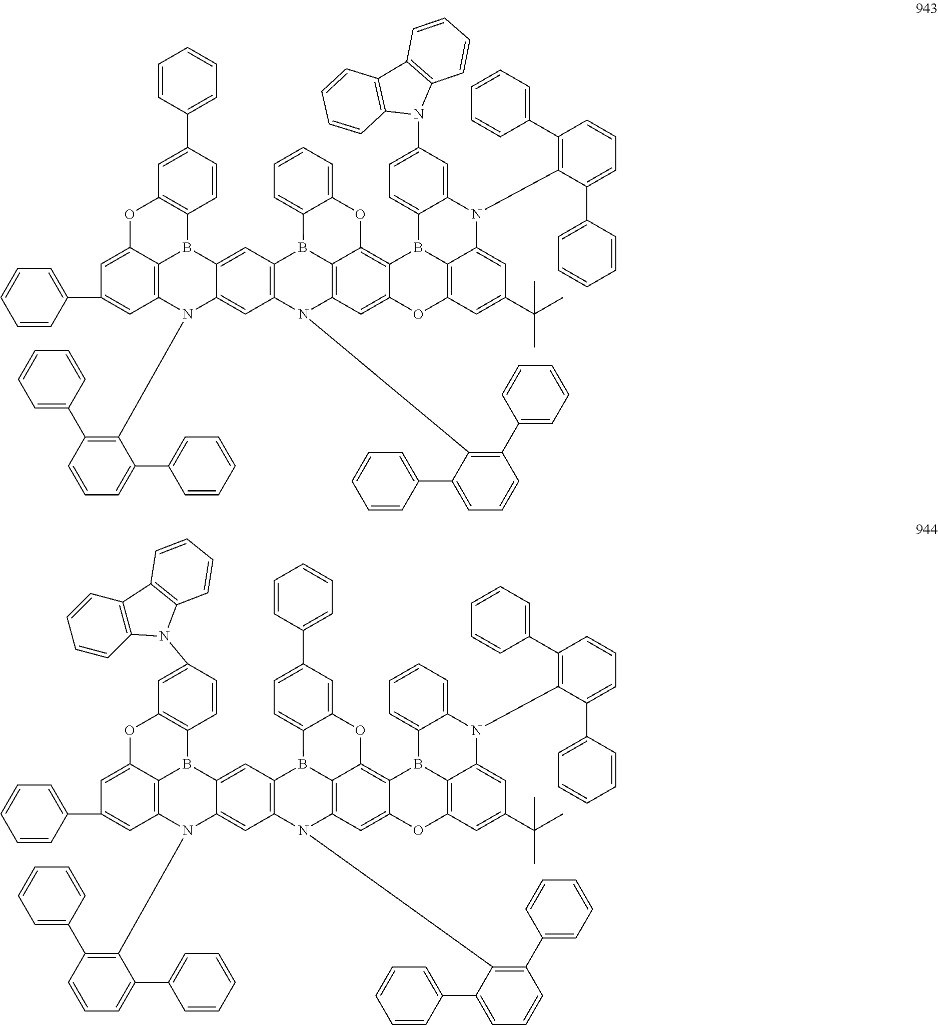

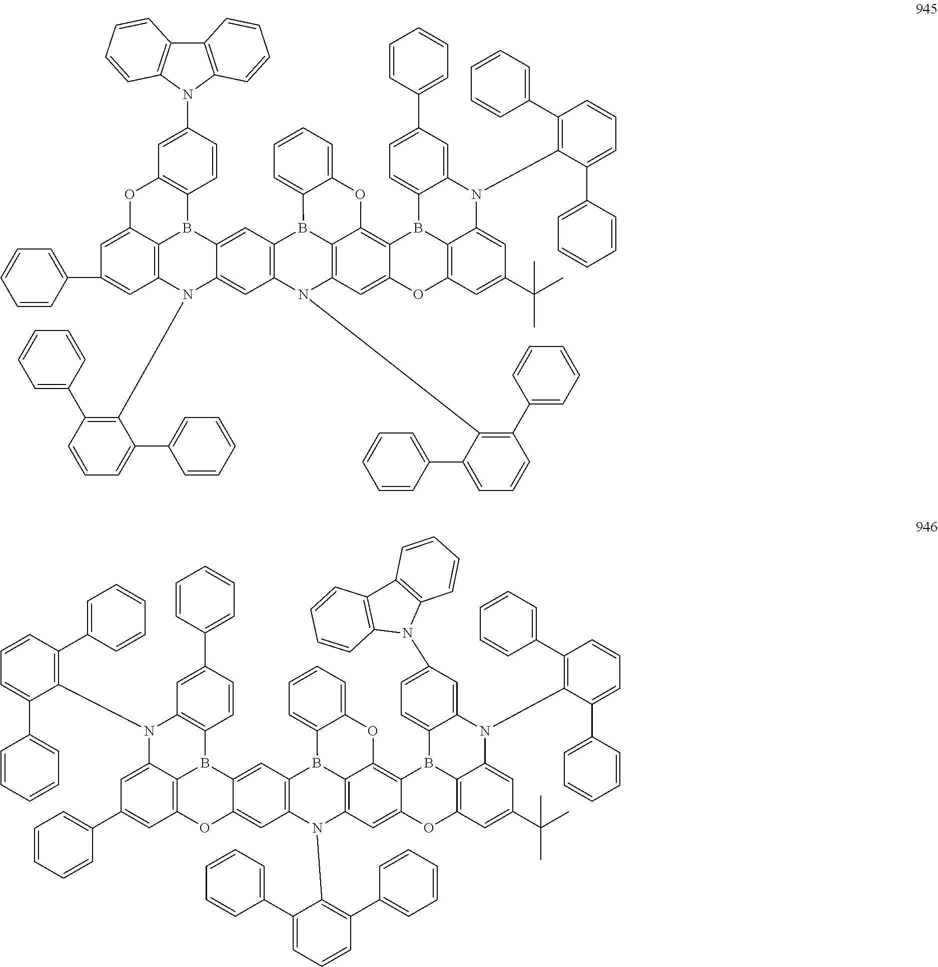 [SMILES: CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-c4ccccc4)cc1N3c1c(-c3ccccc3)cccc1-c1ccccc1)O2]

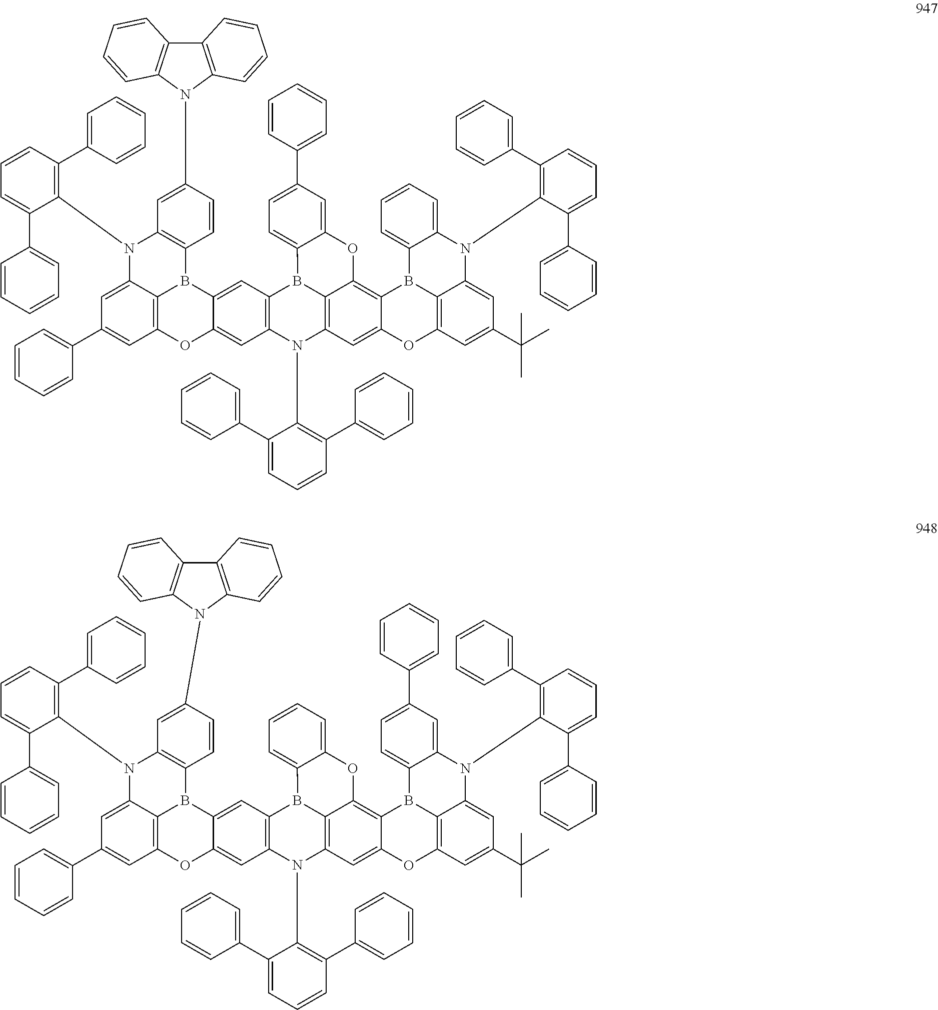 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1N3c1c(-c3ccccc3)cccc1-c1ccccc1)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1N3c1c(-c3ccccc3)cccc1-c1ccccc1)O2]

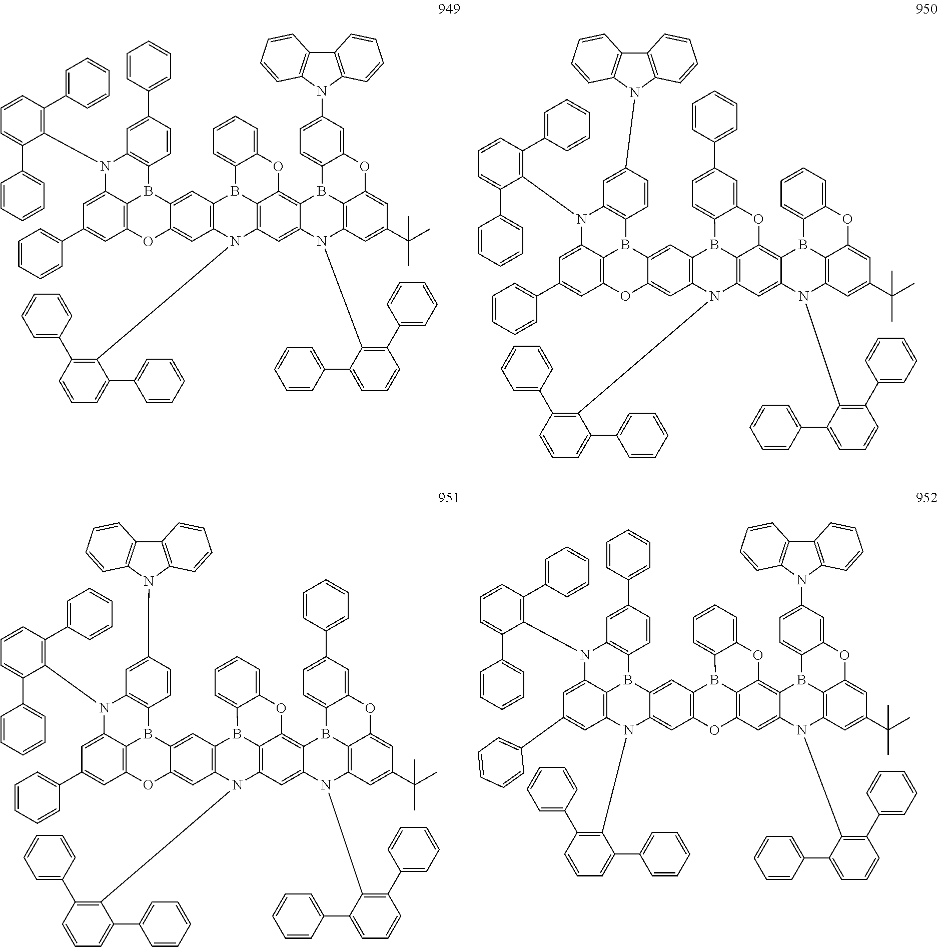

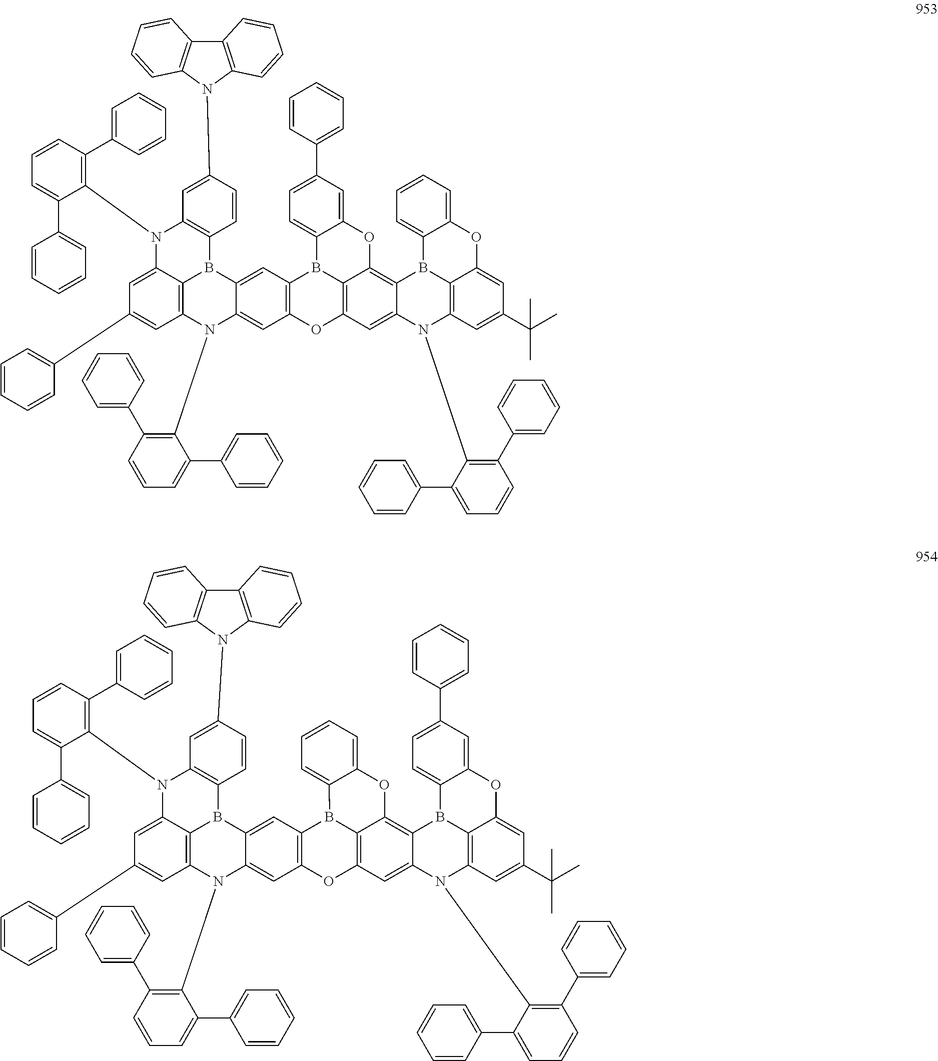 [SMILES: CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1]

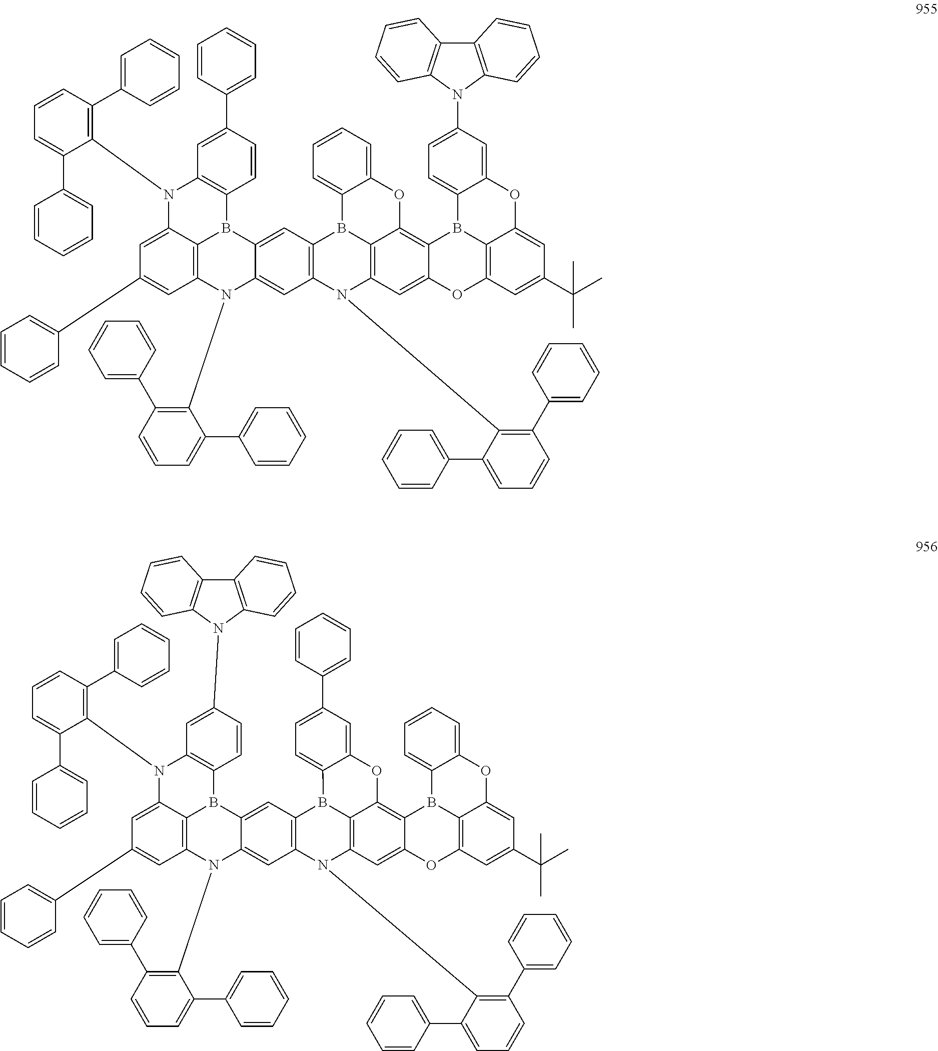 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1]

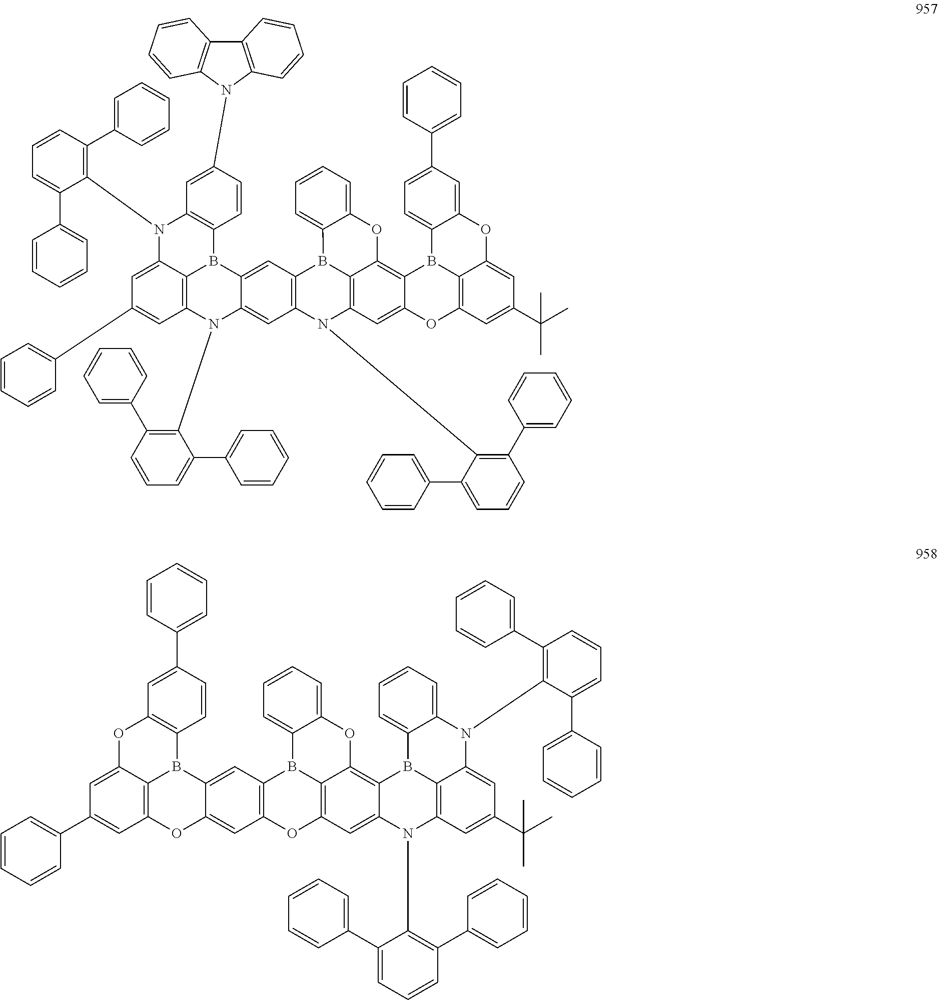 [SMILES: CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)Oc1cc(-c3ccccc3)cc3c1B2c1ccc(-c2ccccc2)cc1O3]

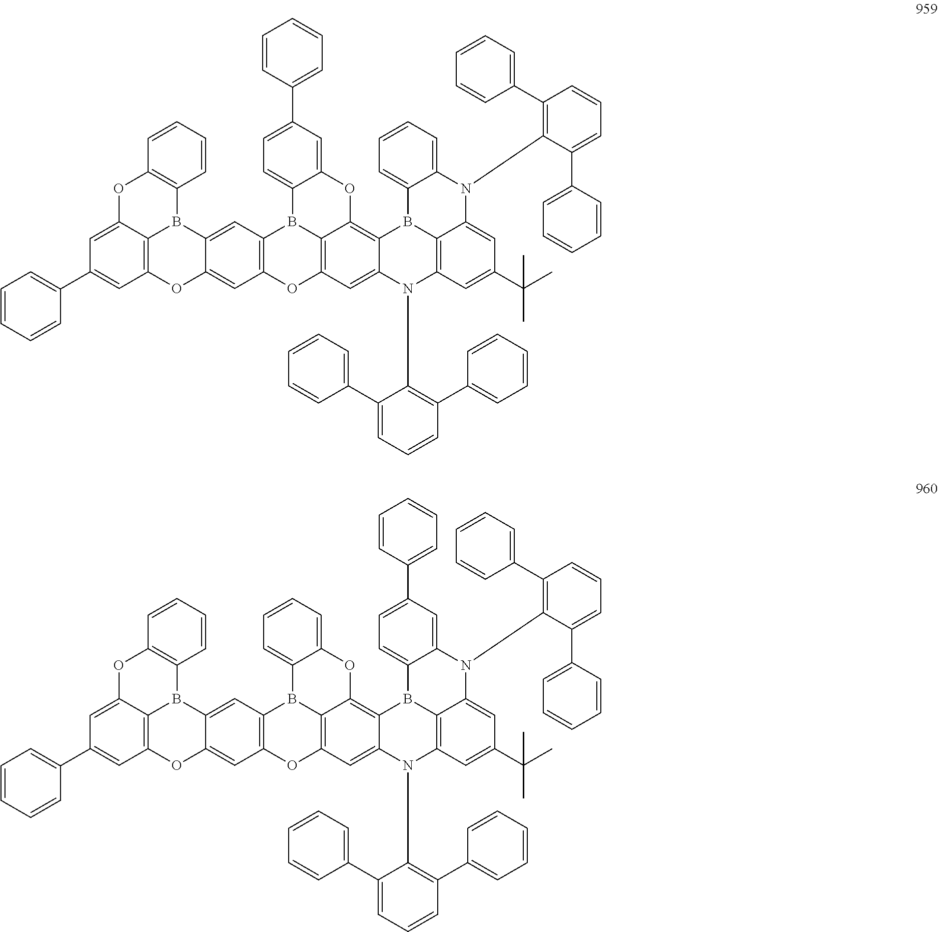

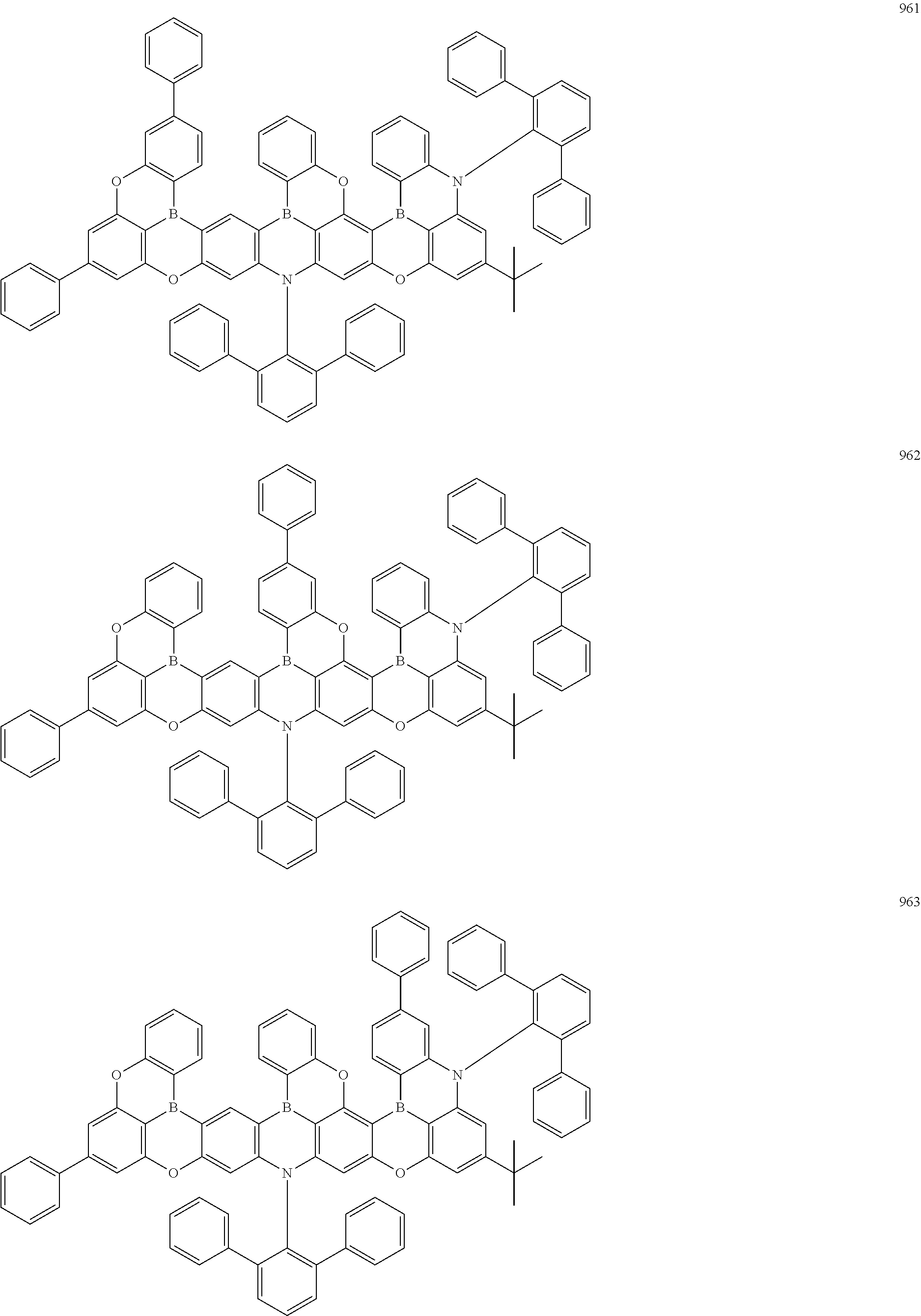

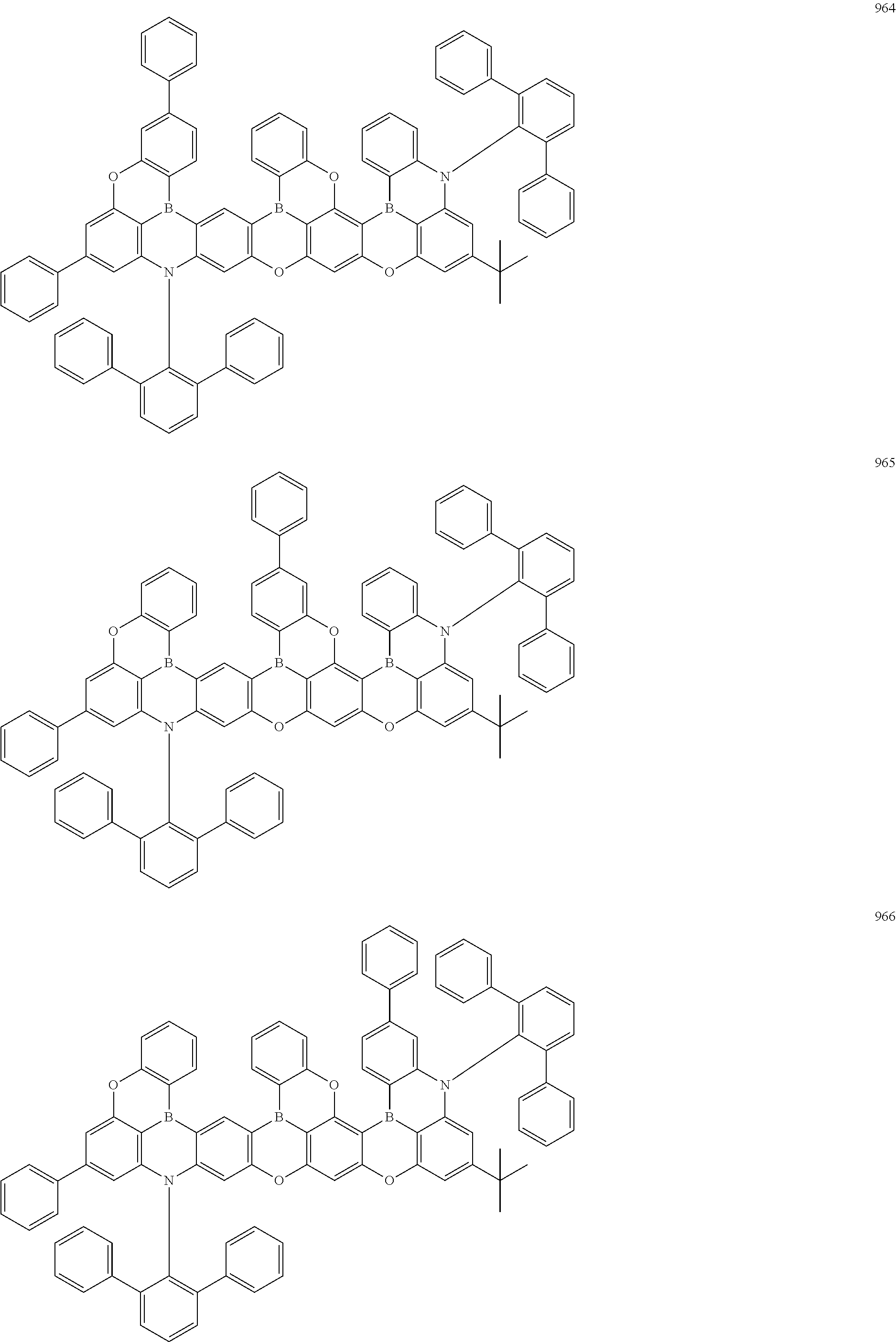

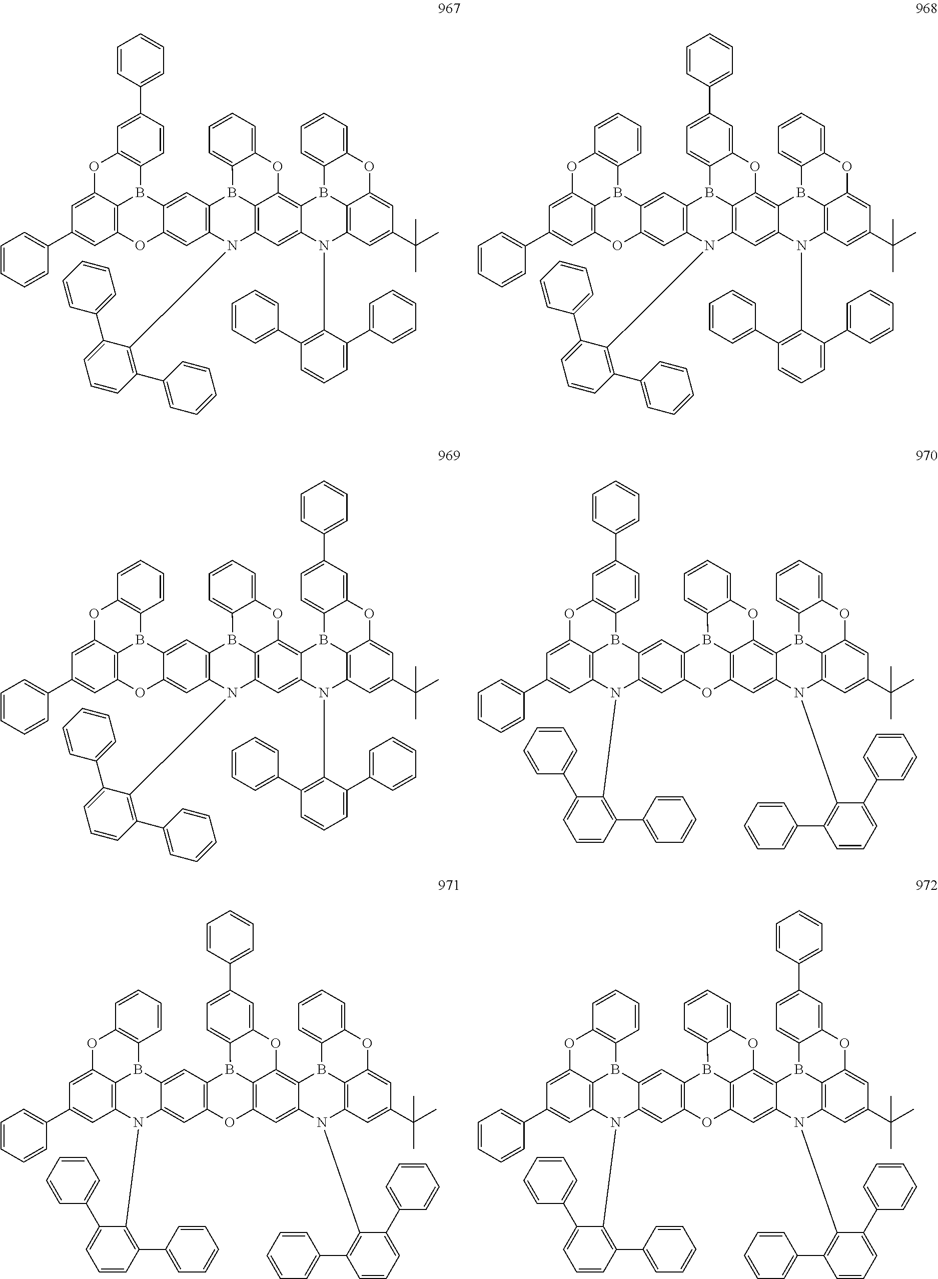

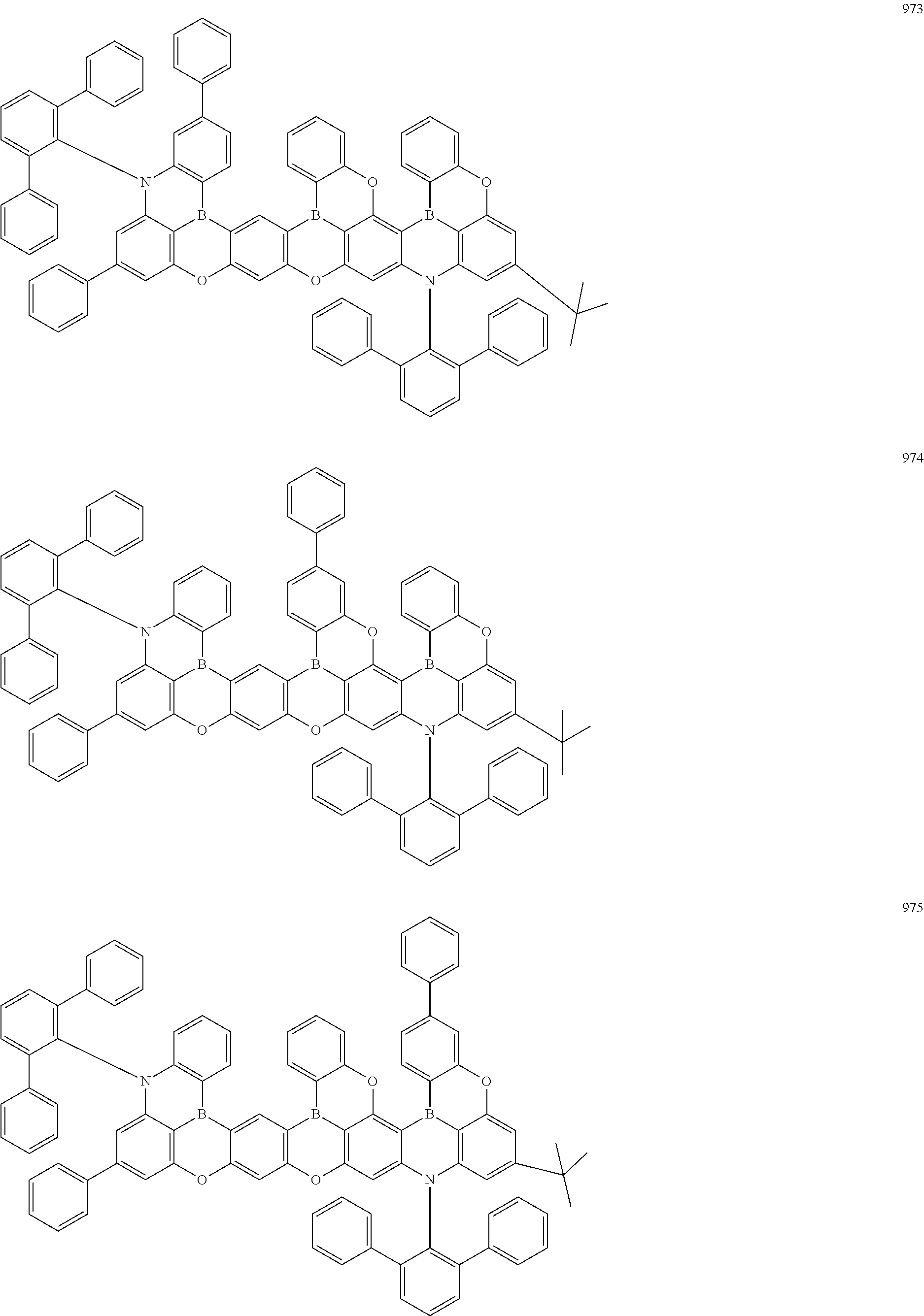

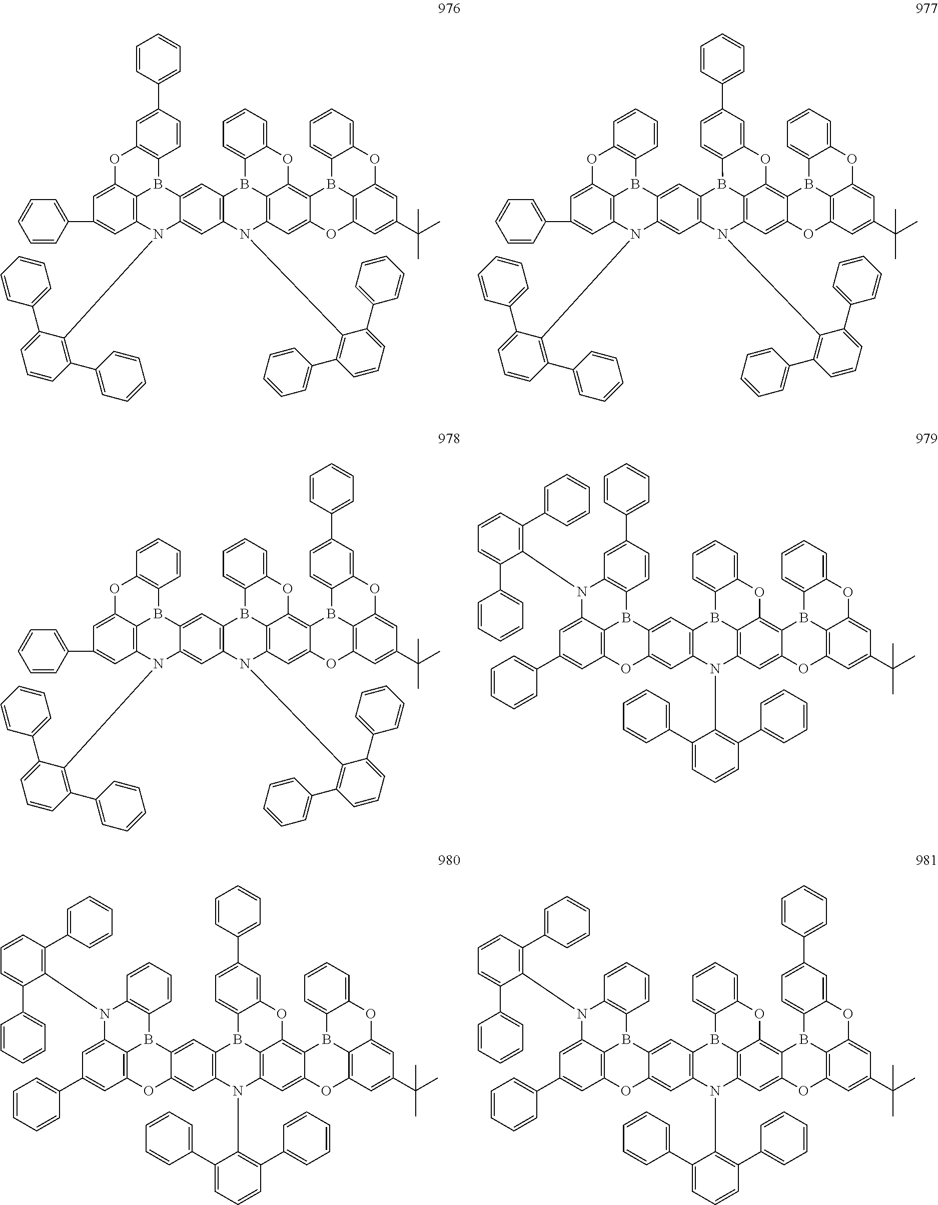

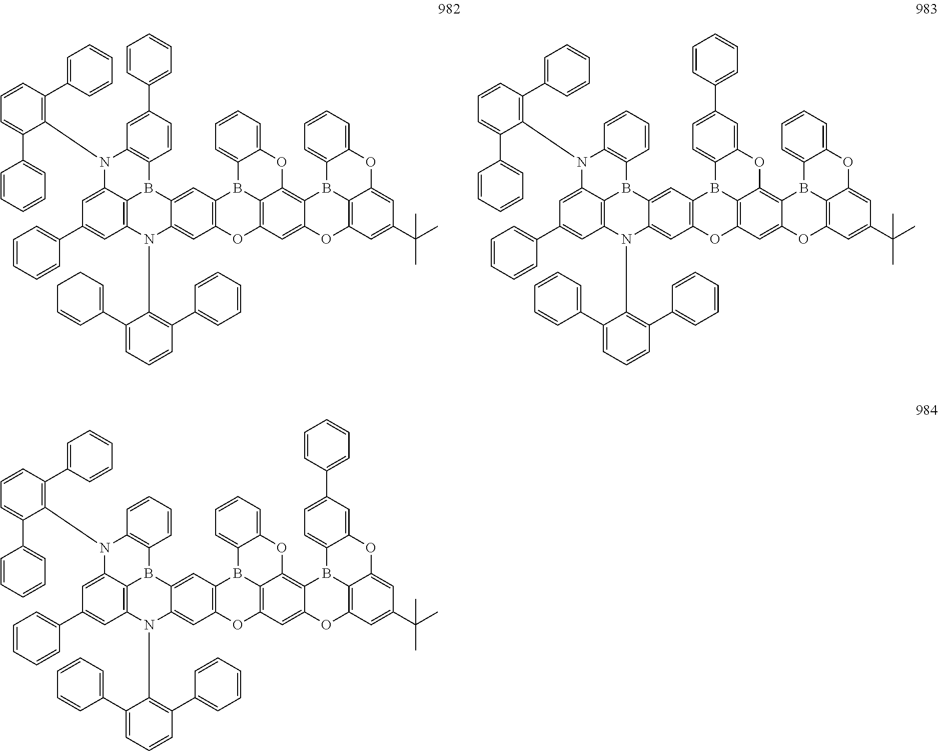

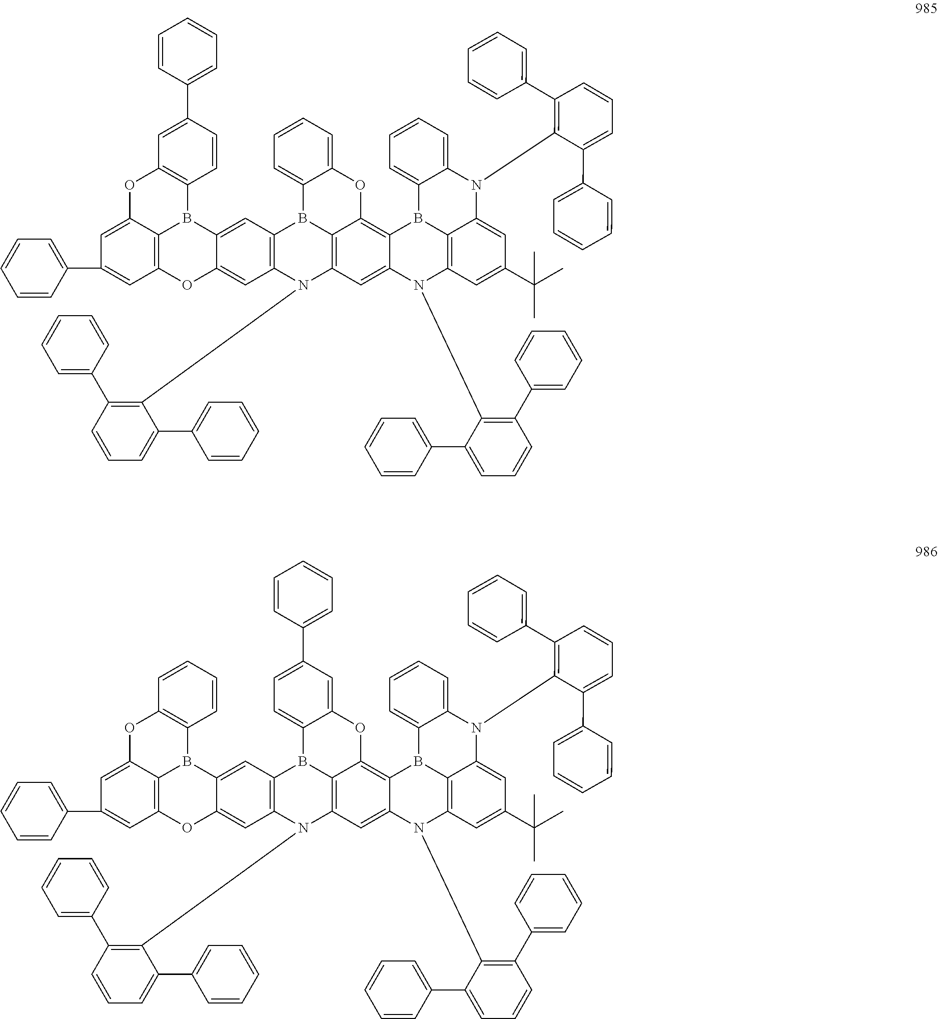 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccc(-c2ccccc2)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1cc2c(cc1N4c1c(-c3ccccc3)cccc1-c1ccccc1)Oc1cc(-c3ccccc3)cc3c1B2c1ccccc1O3]

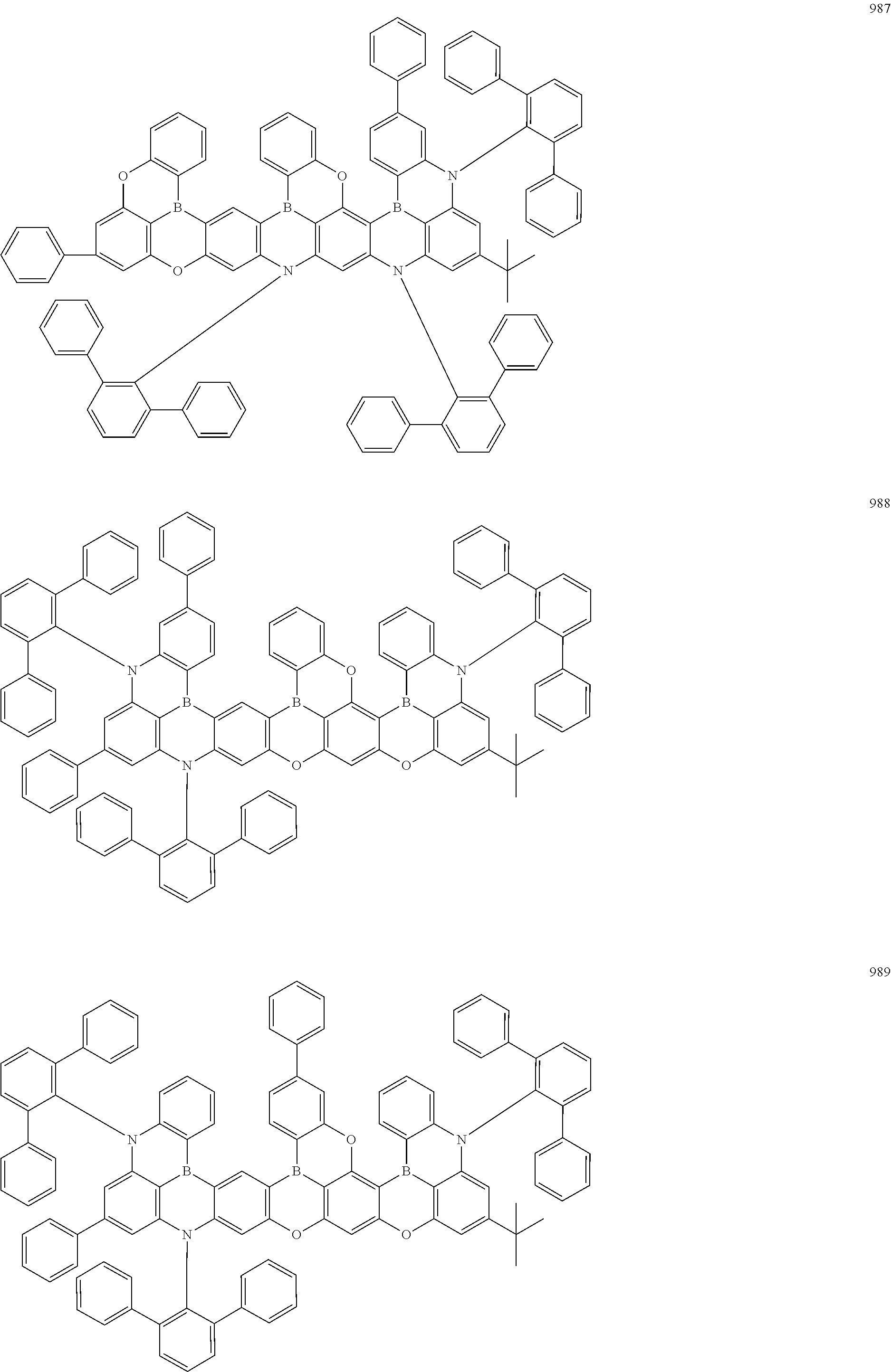

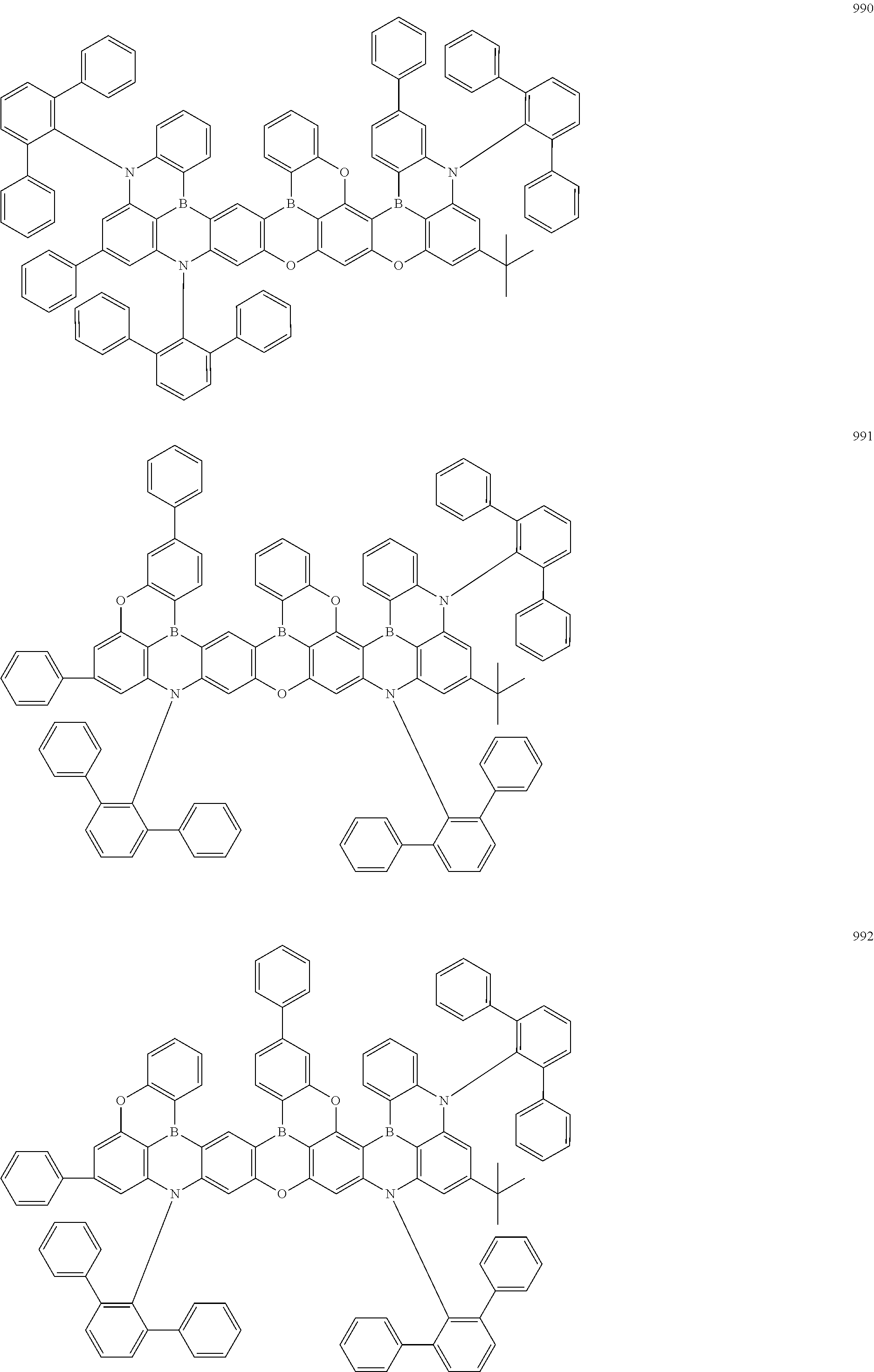

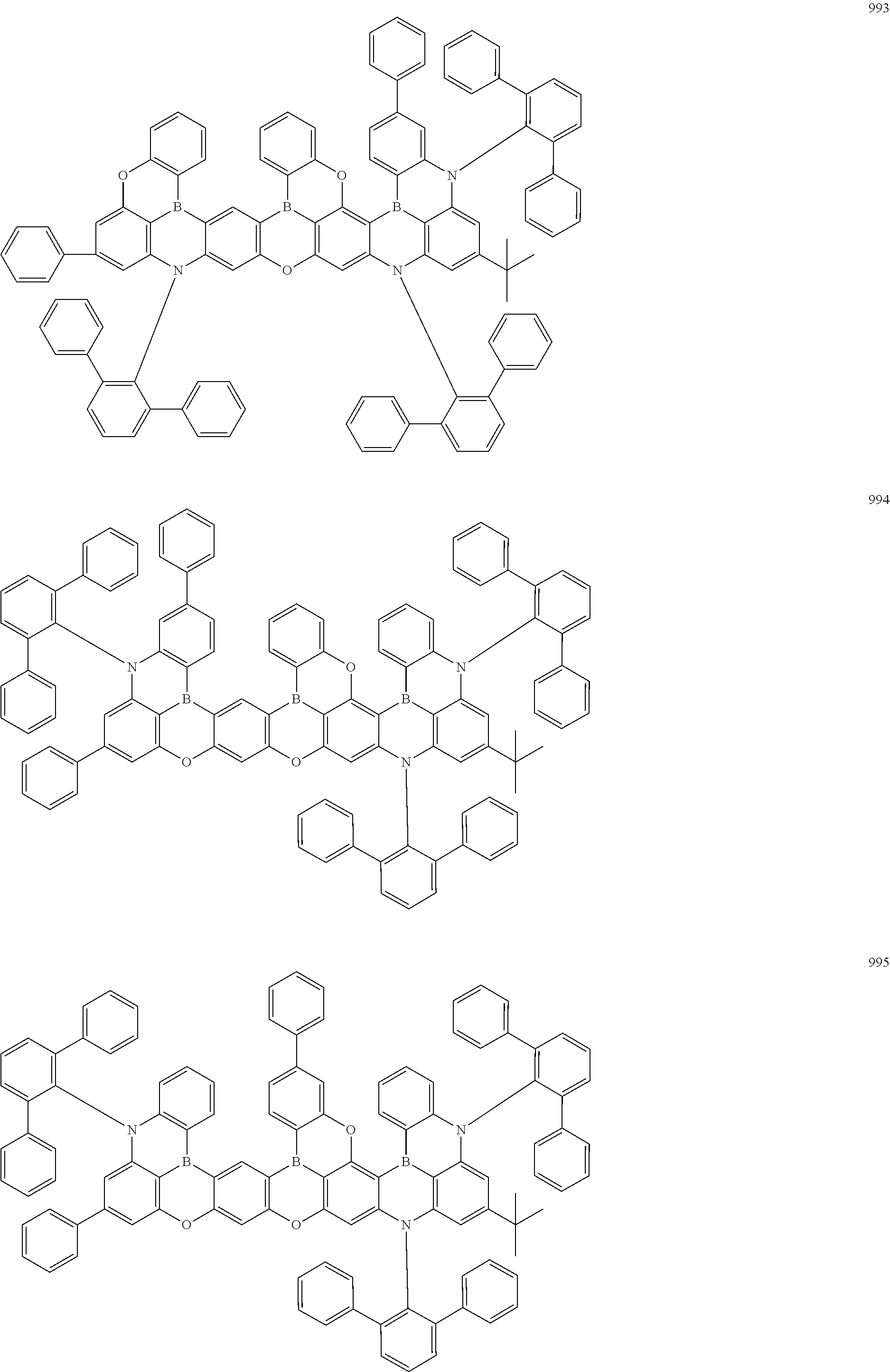

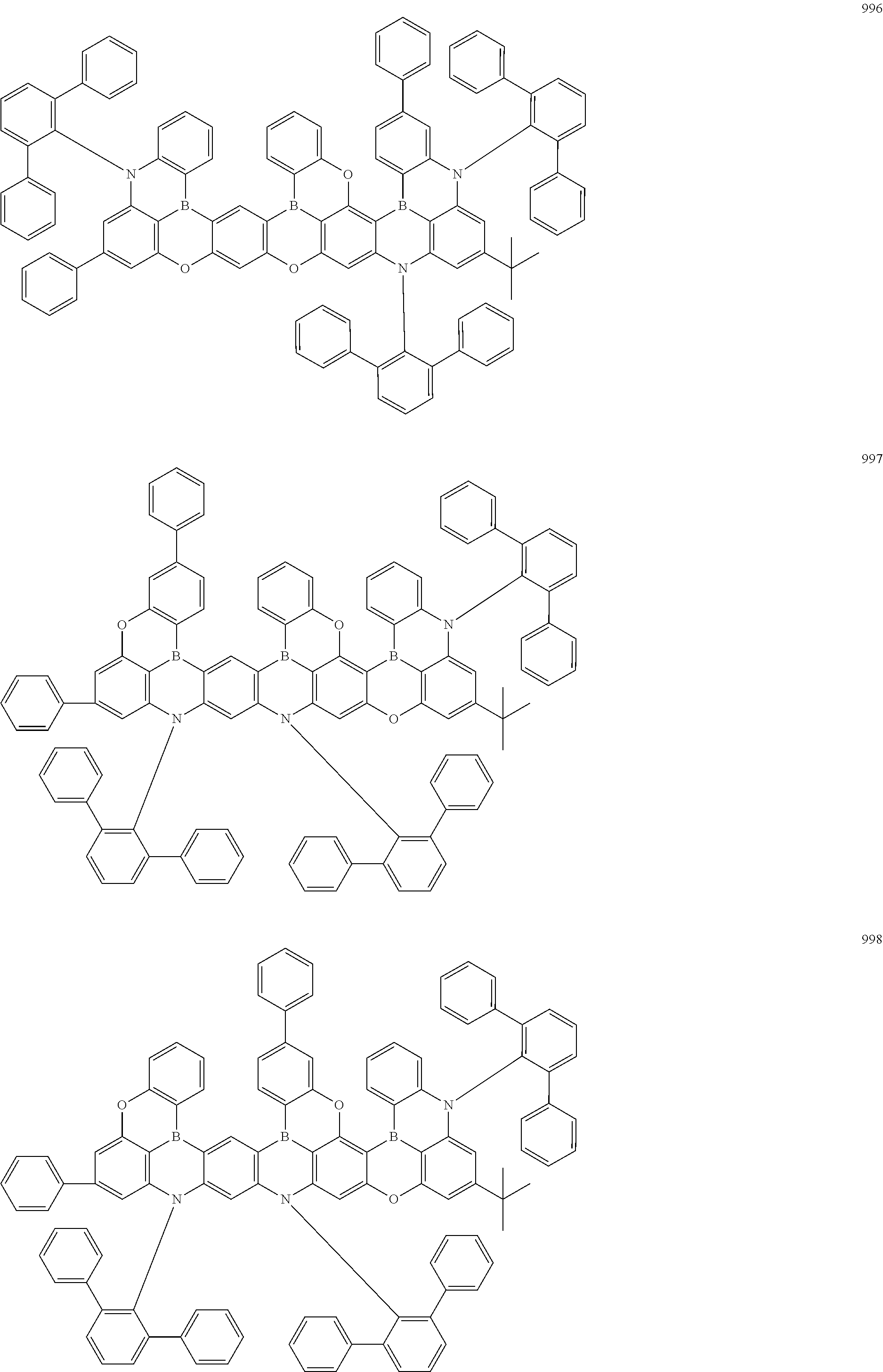

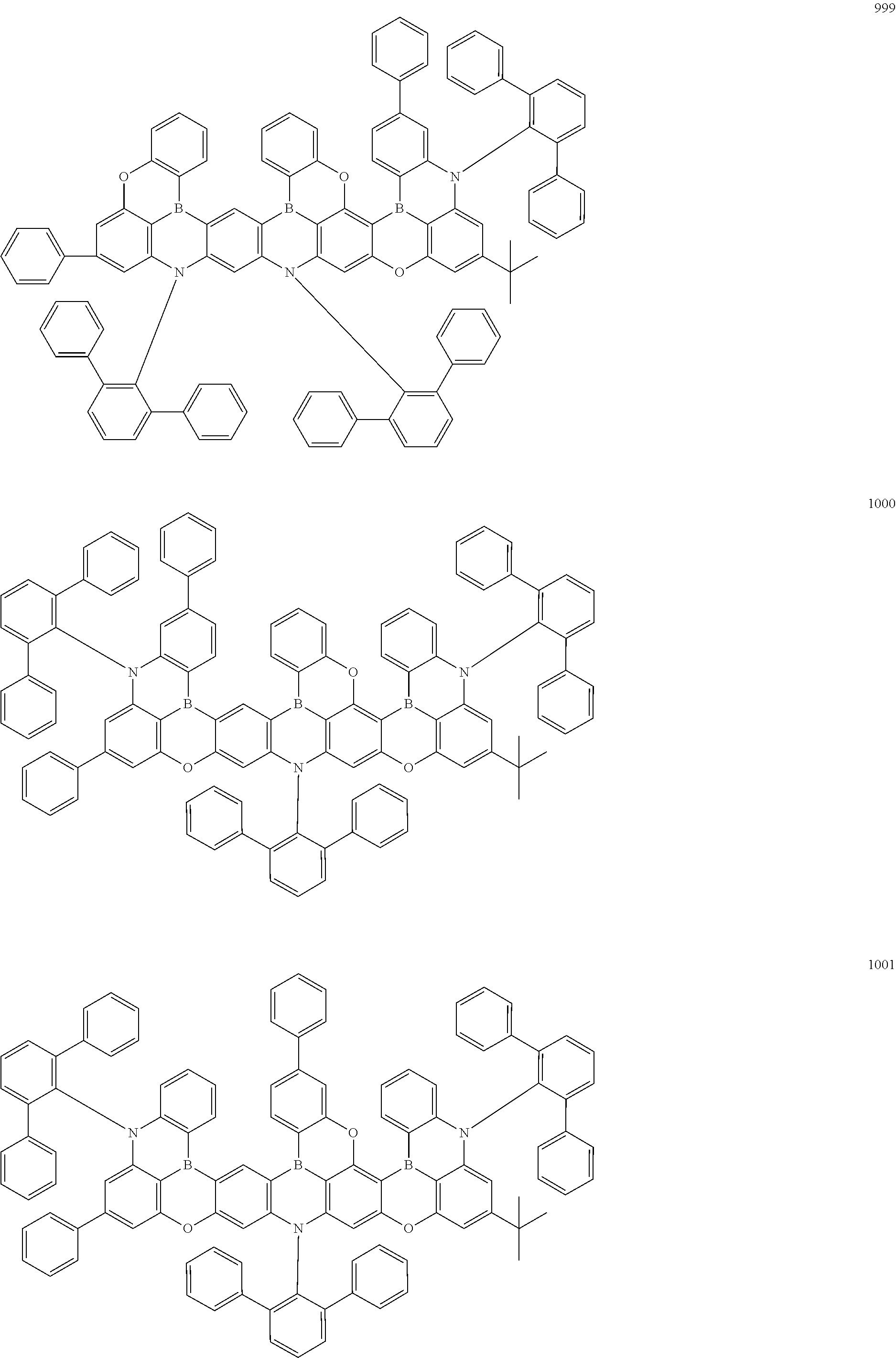

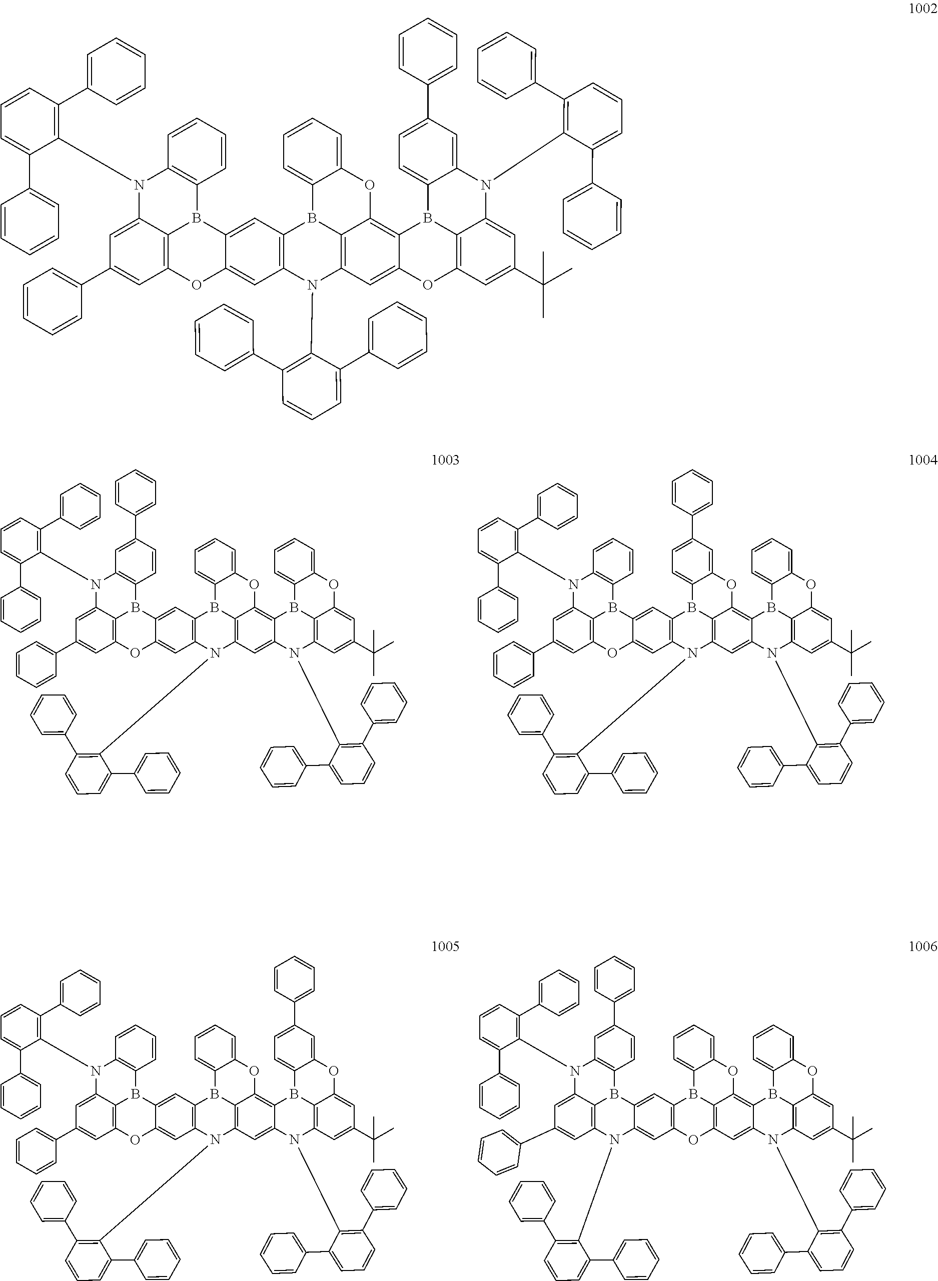

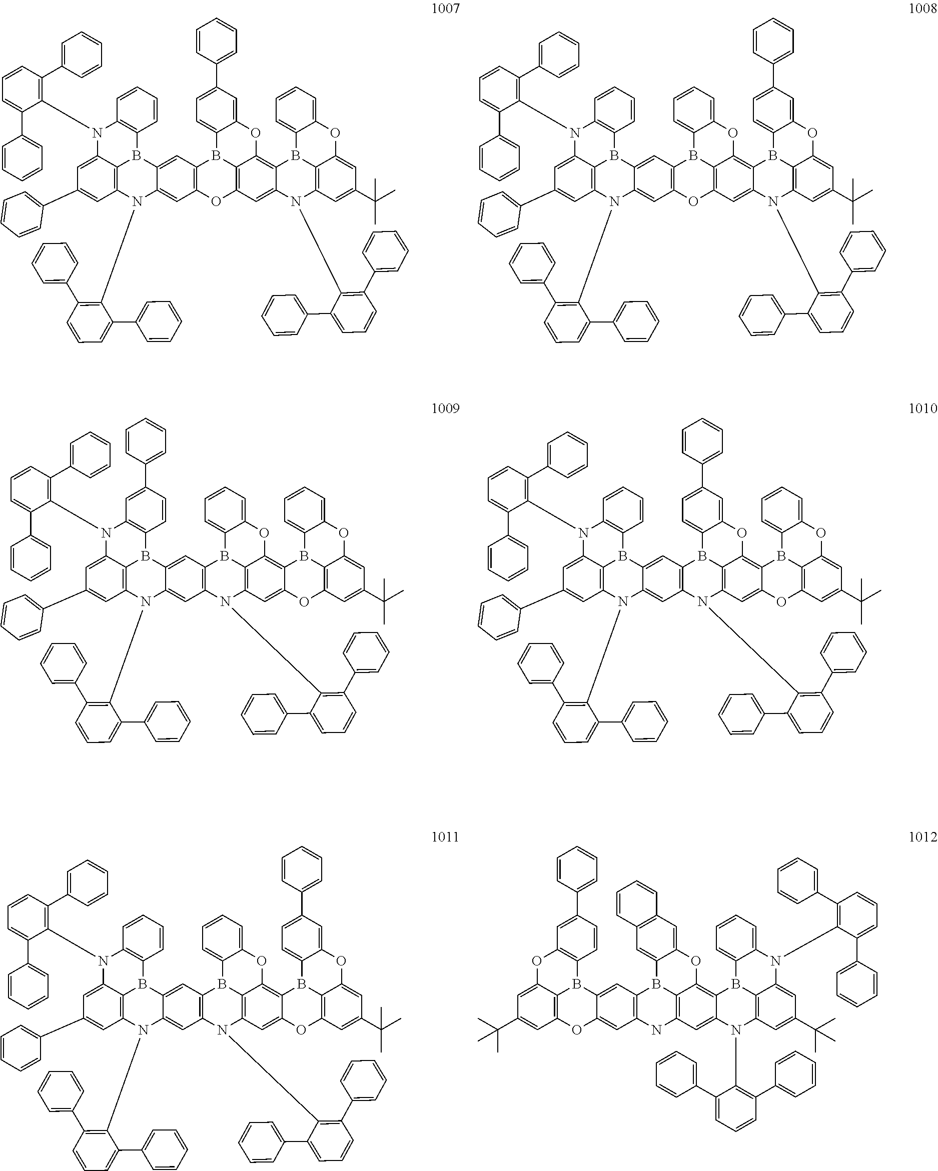

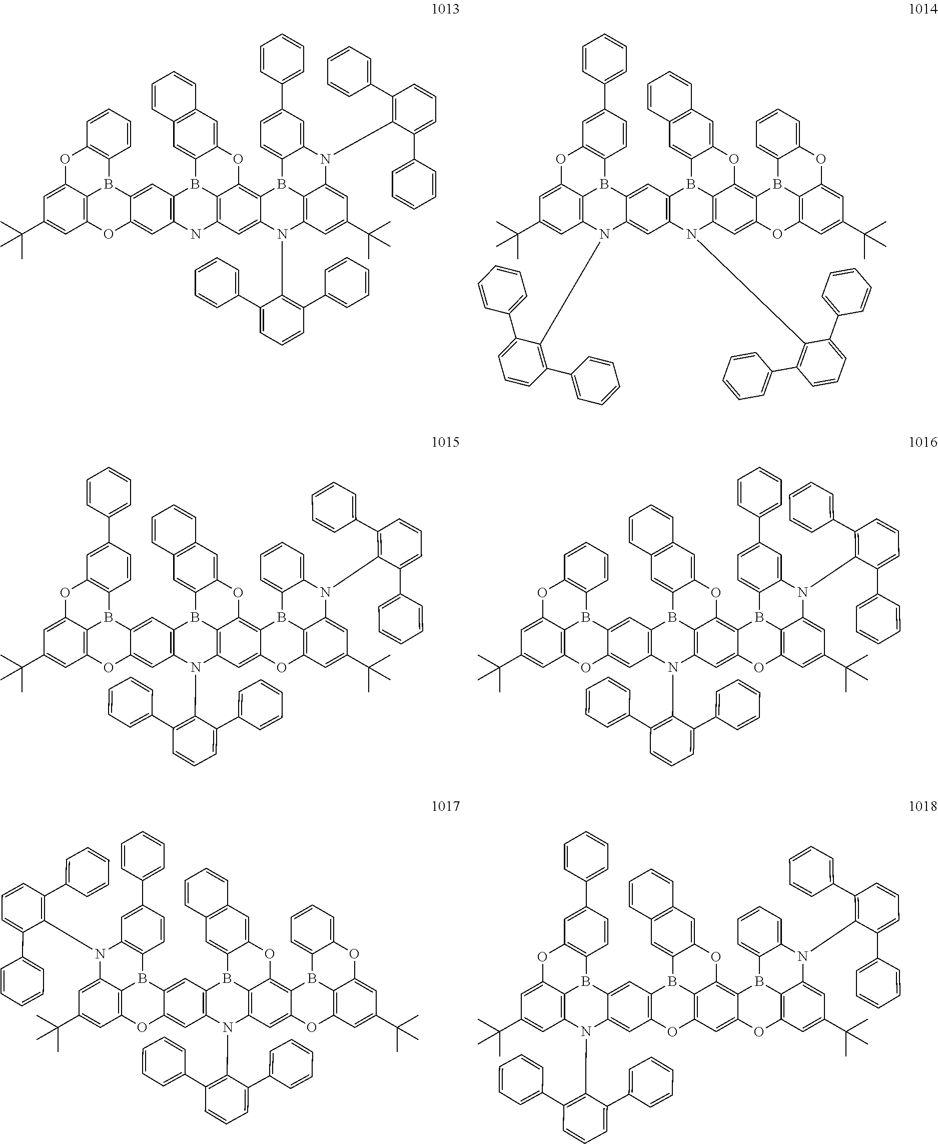

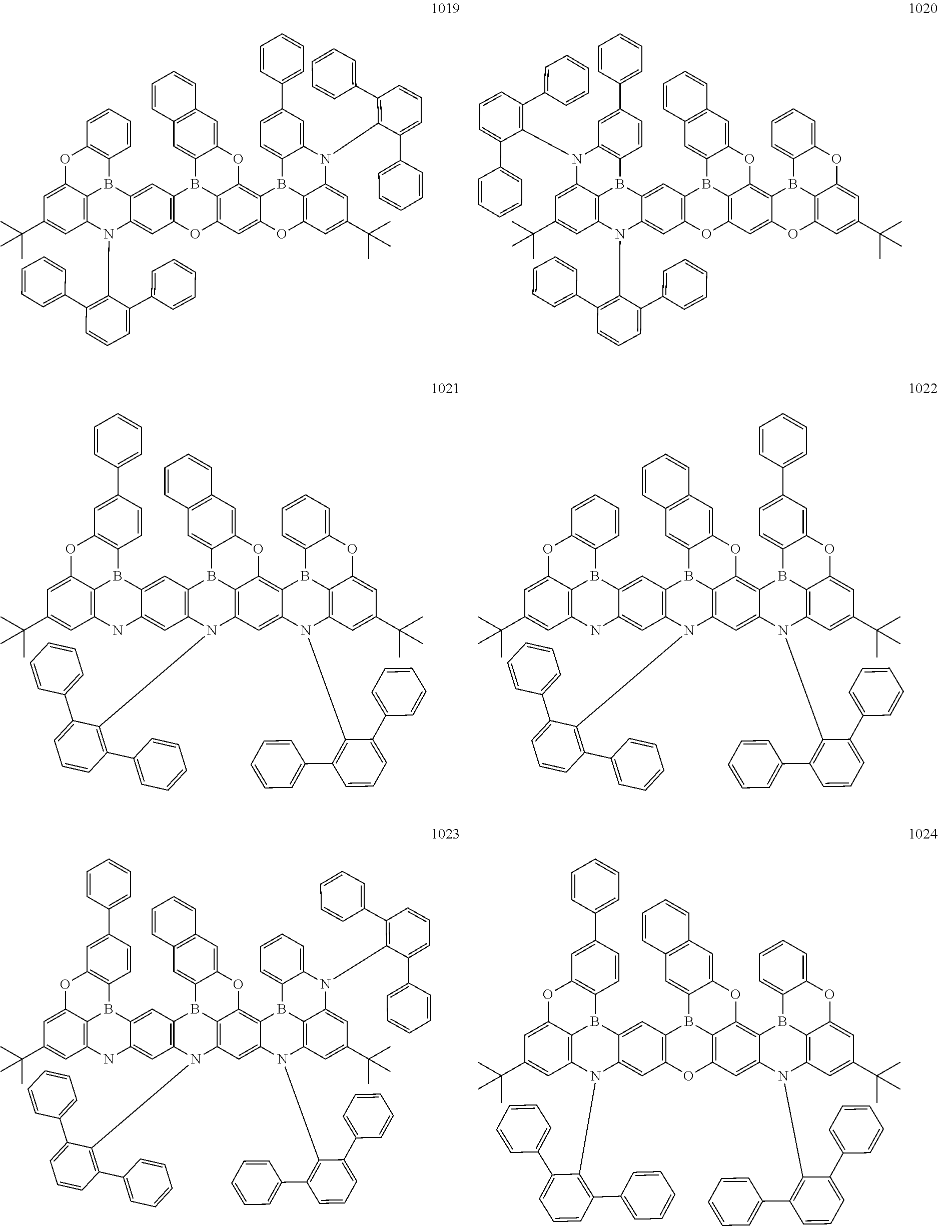

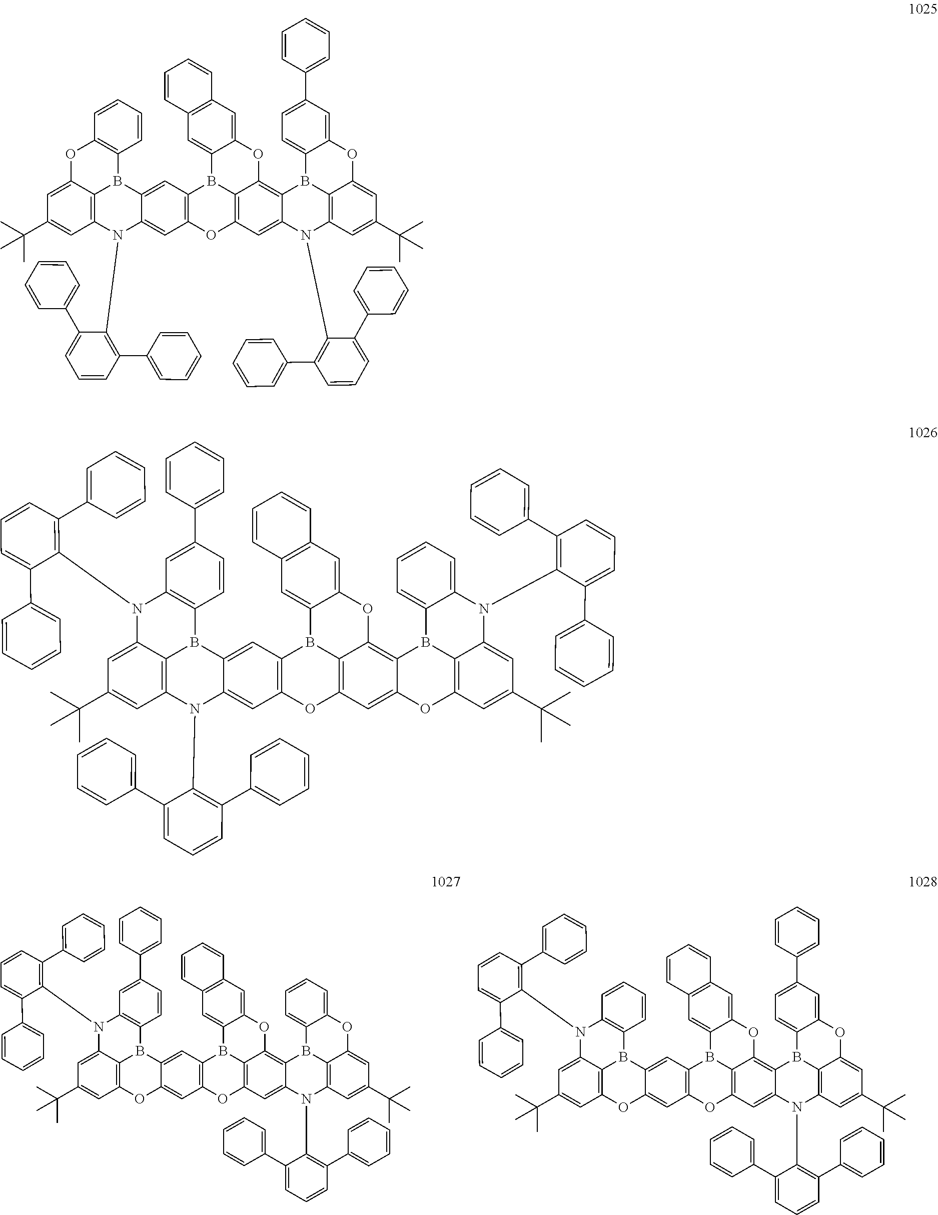

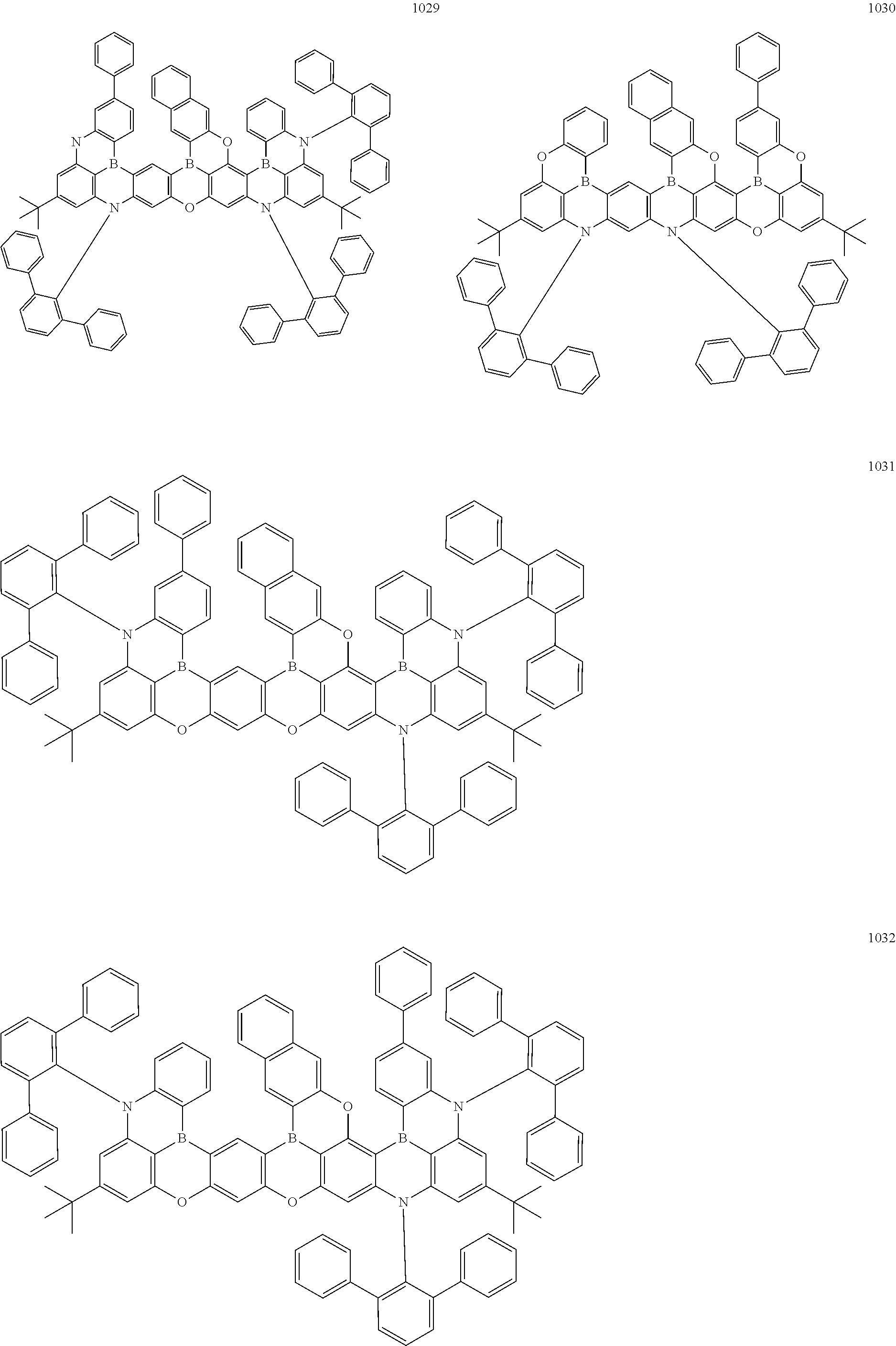

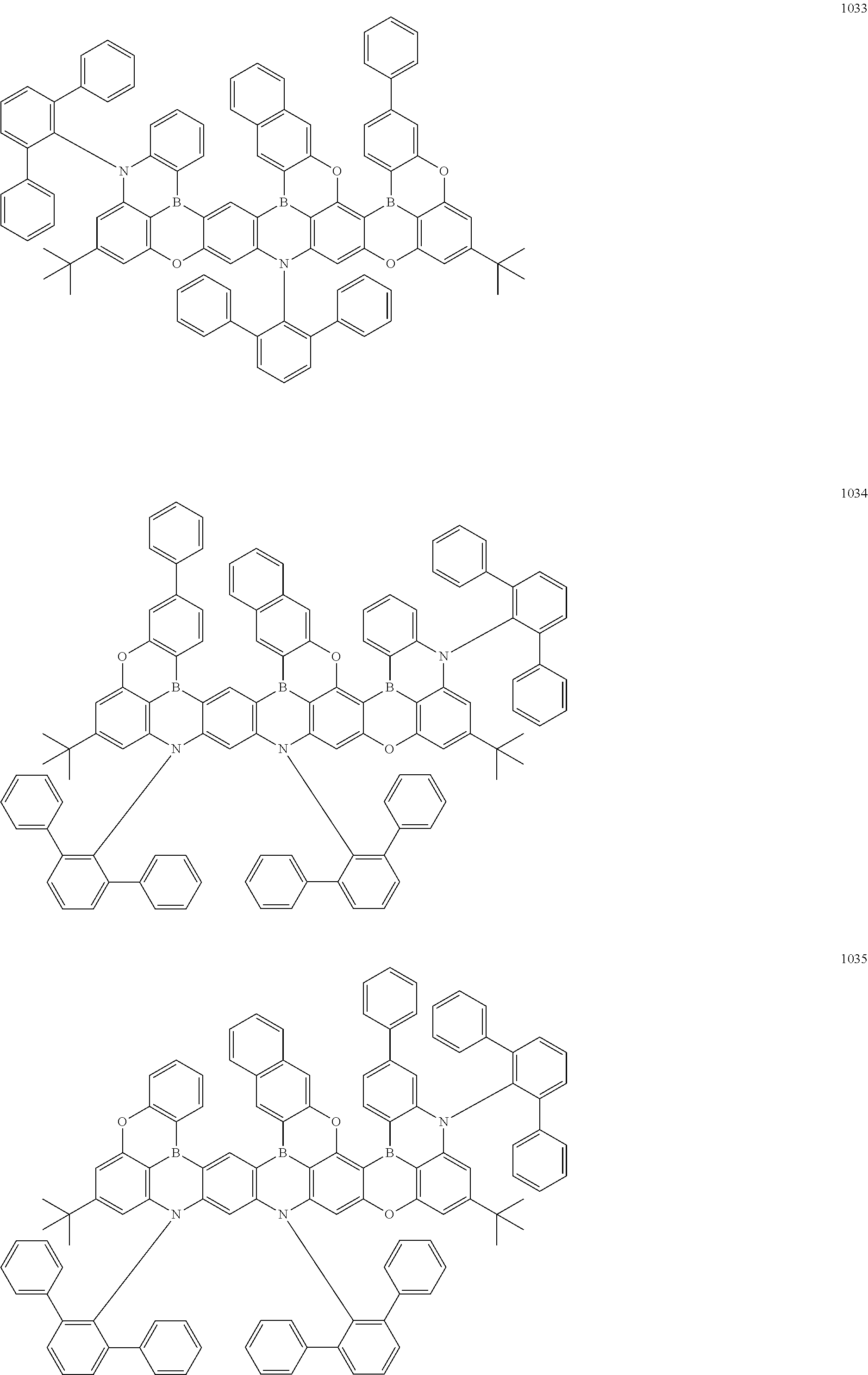

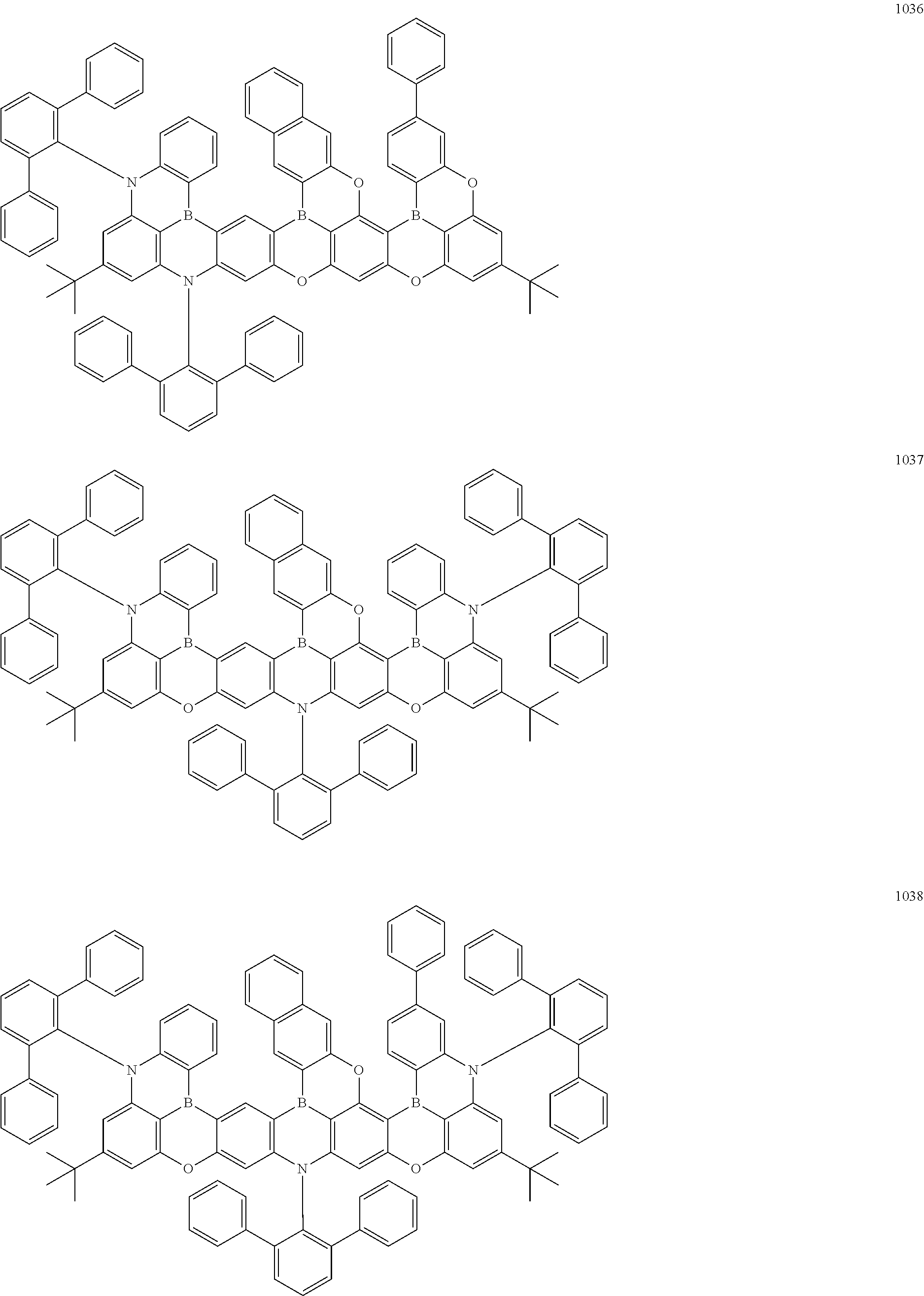

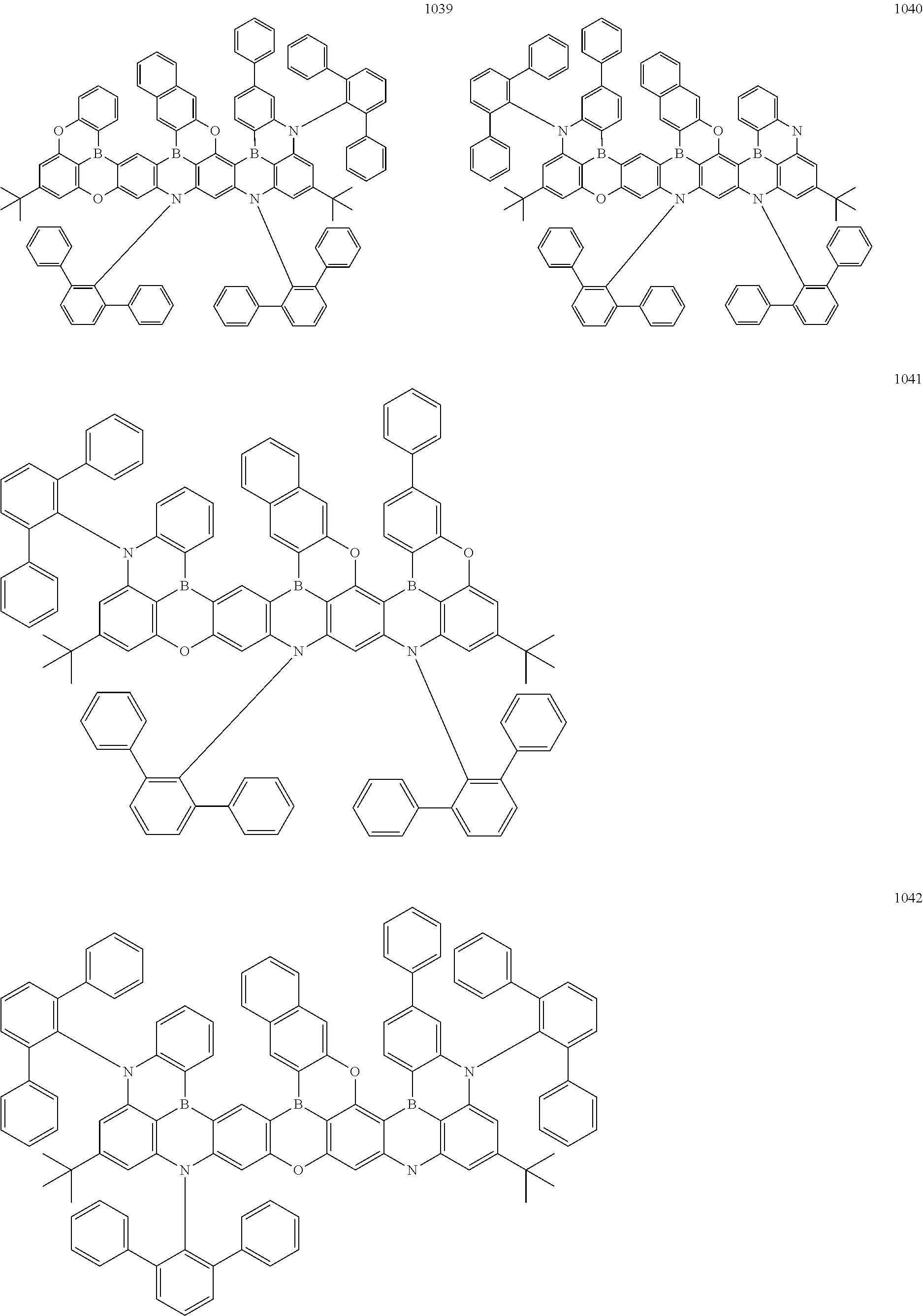

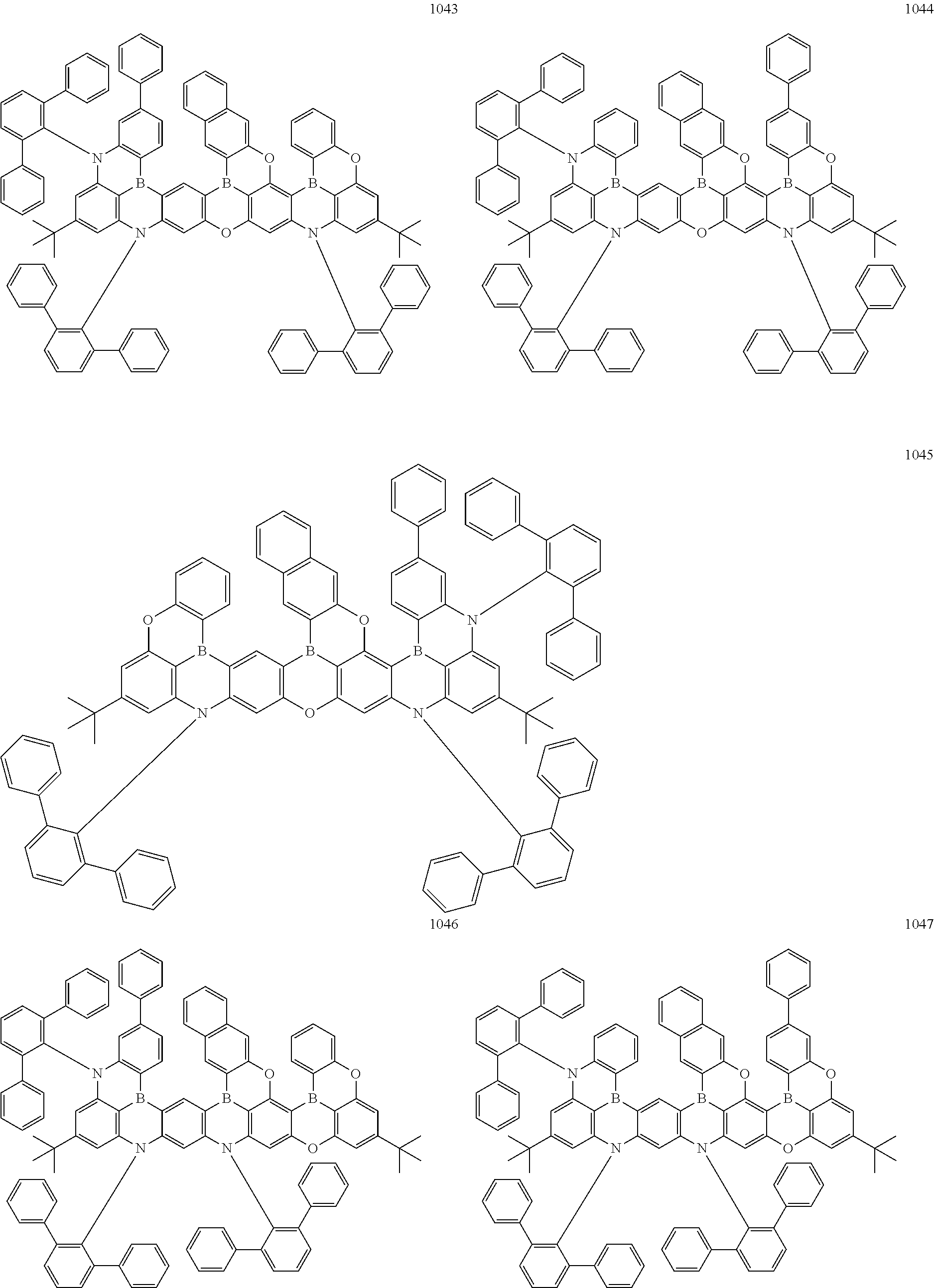

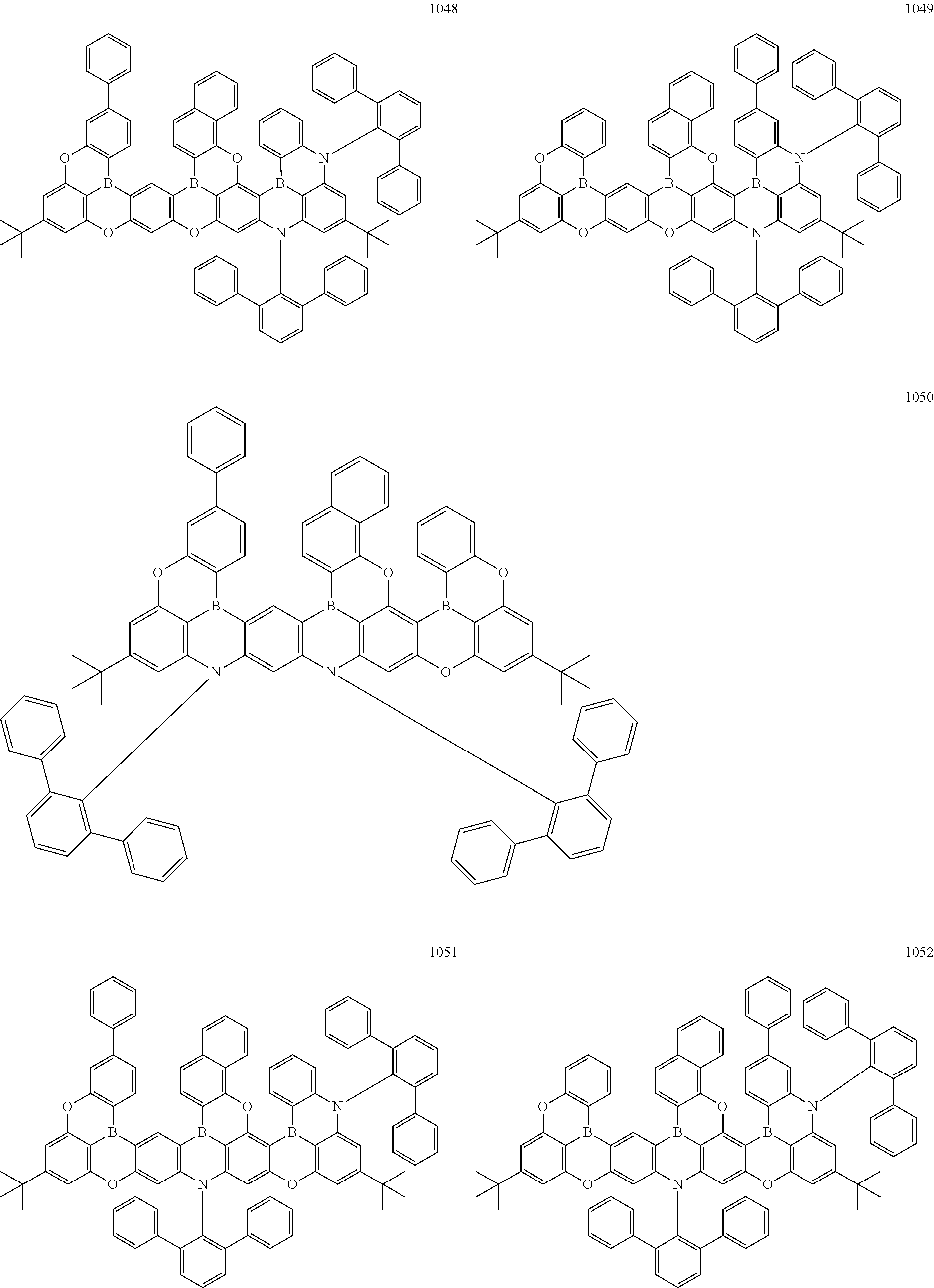

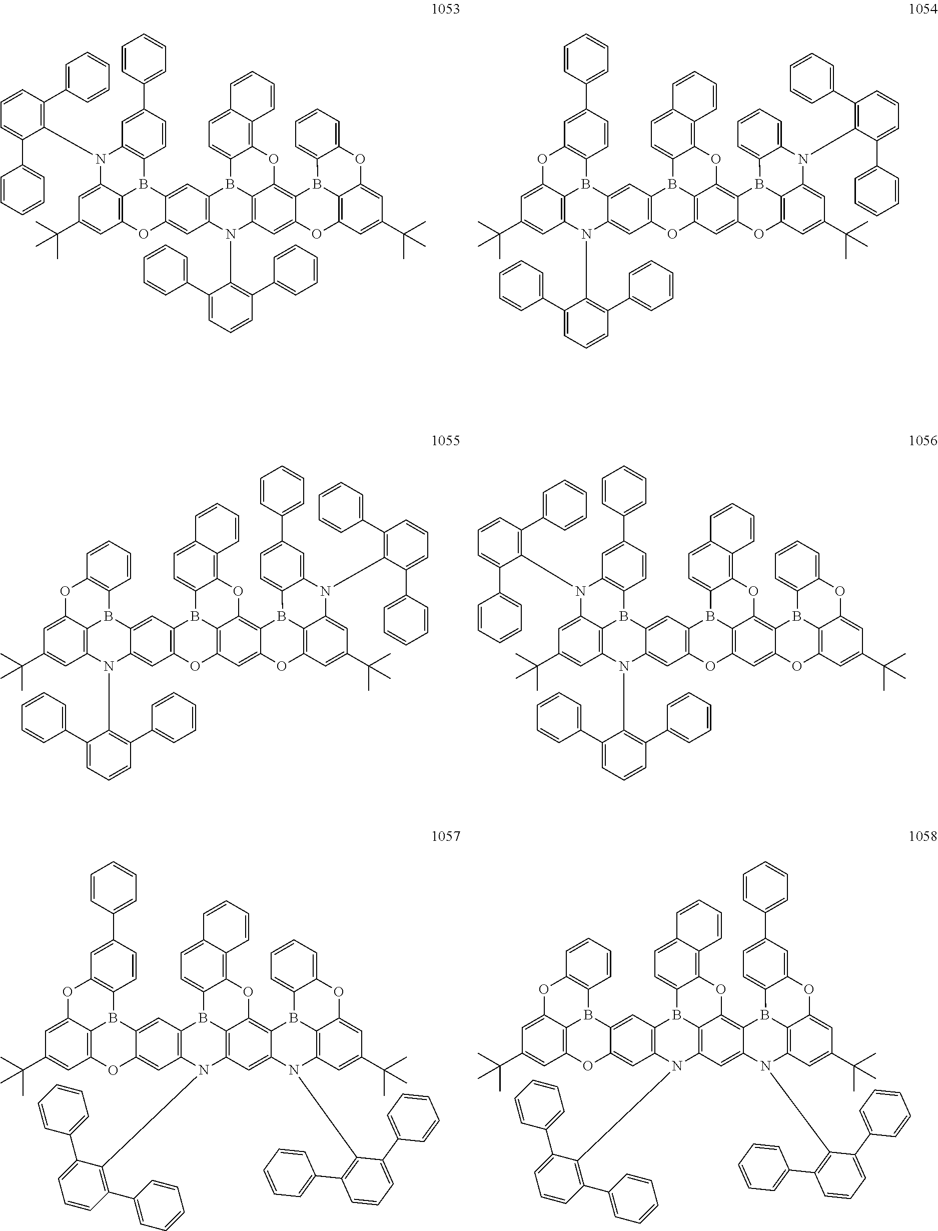

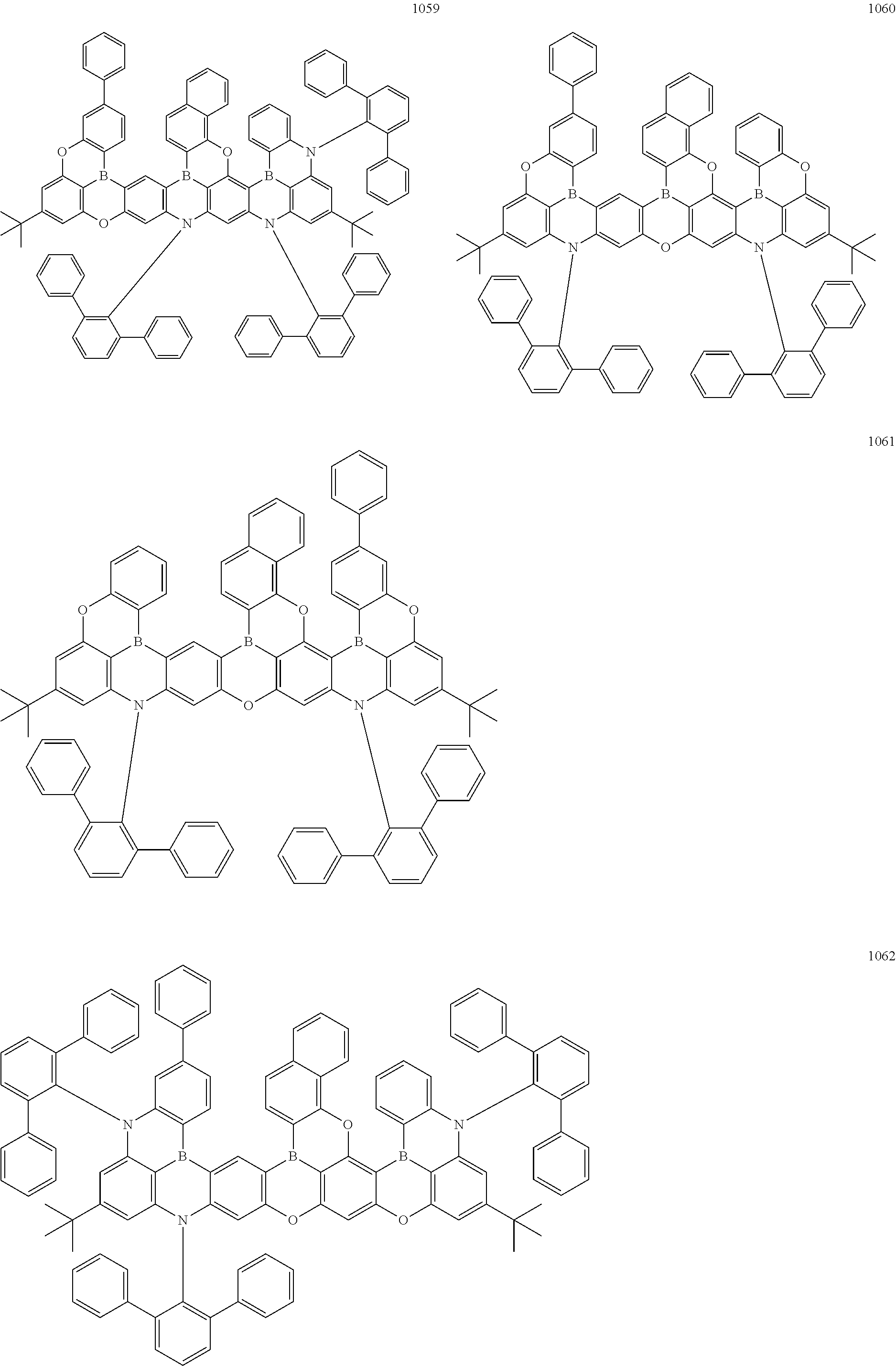

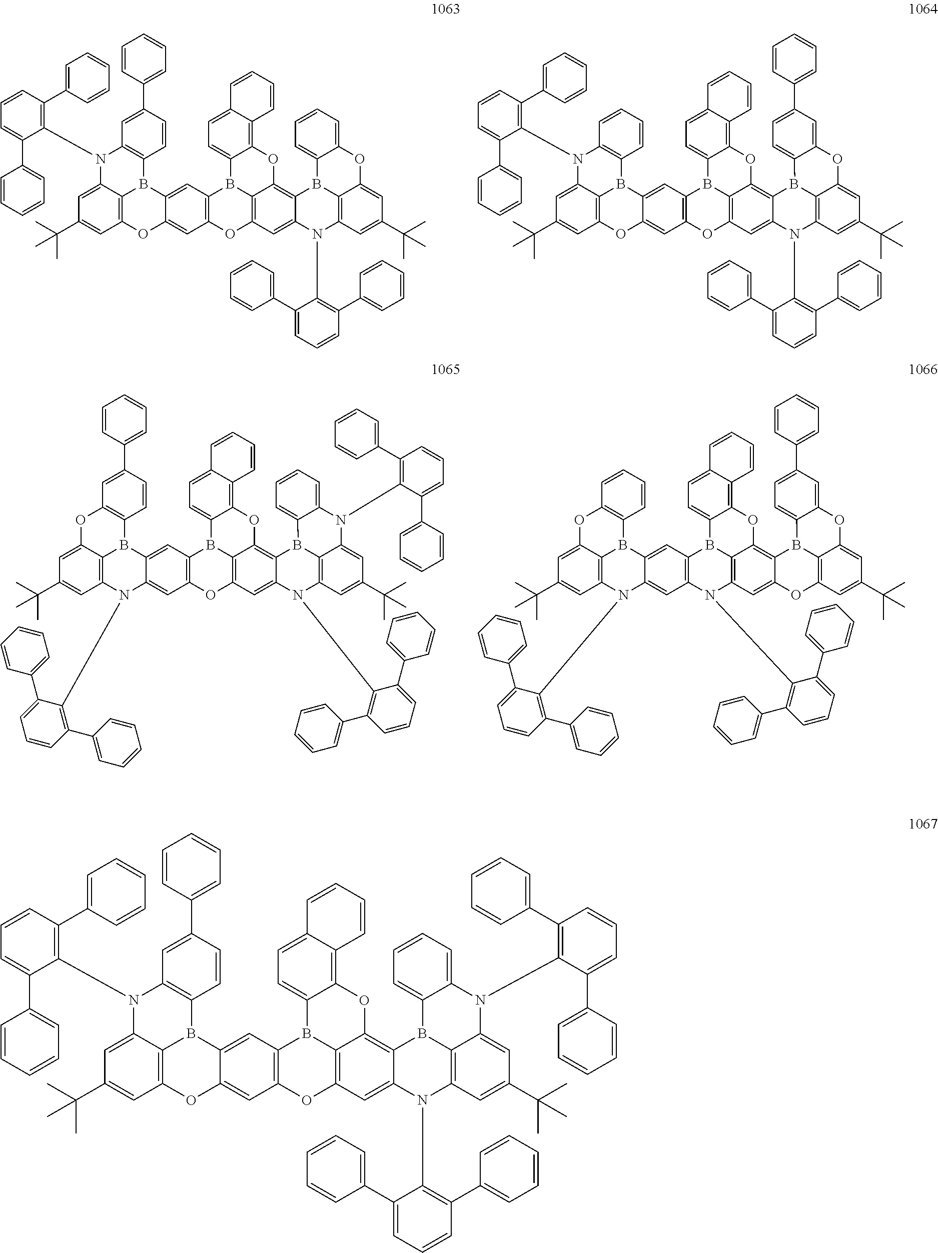

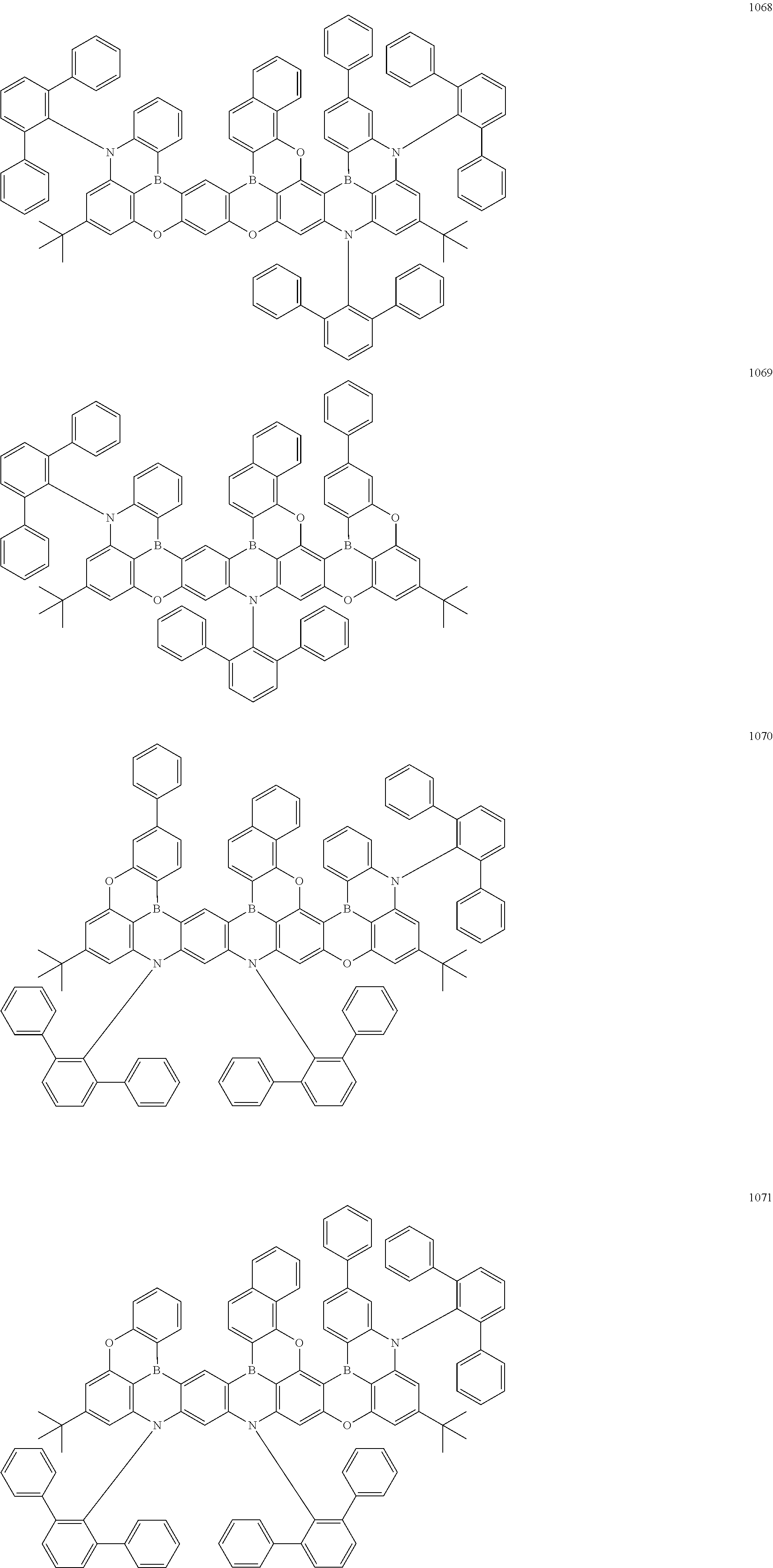

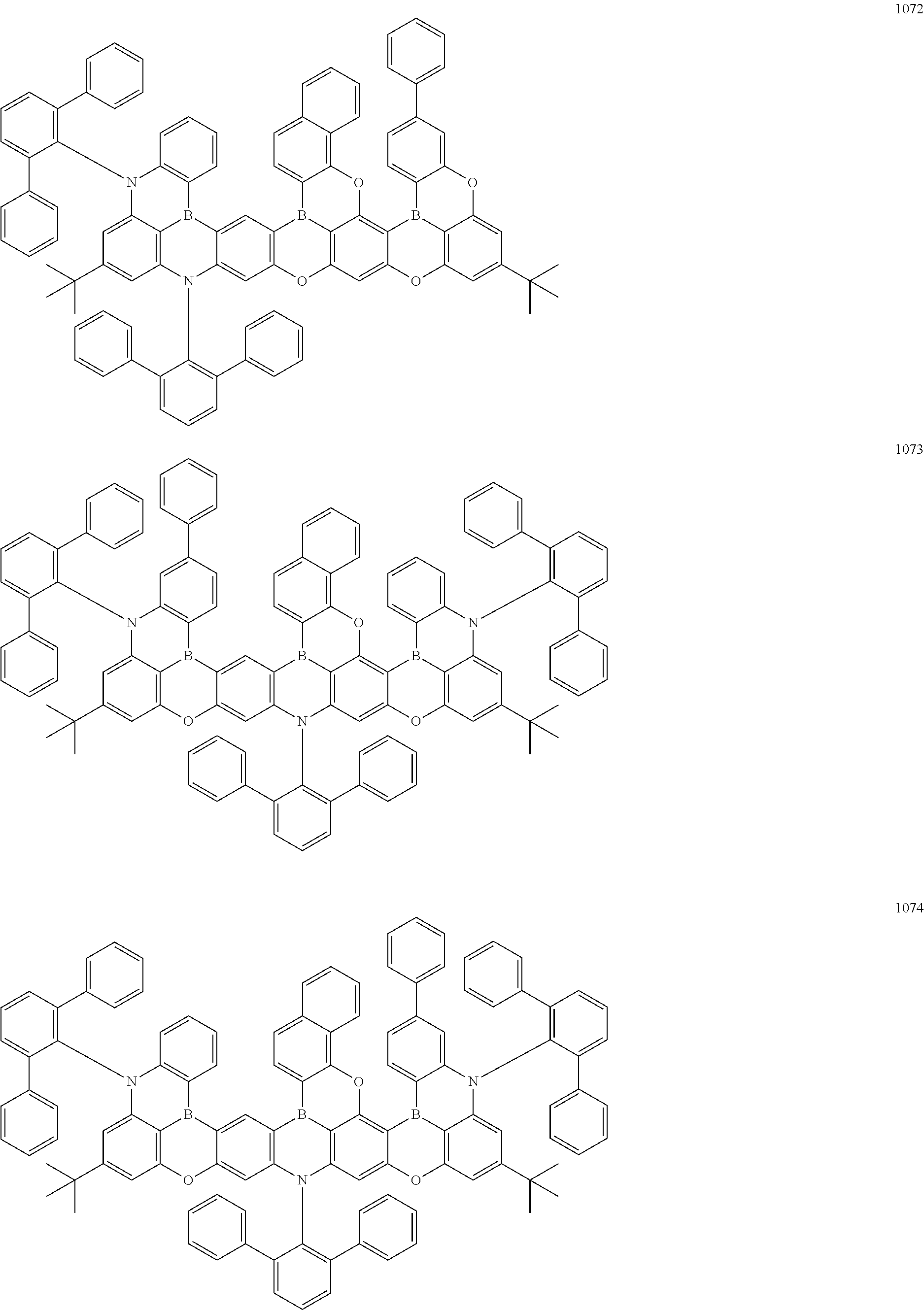

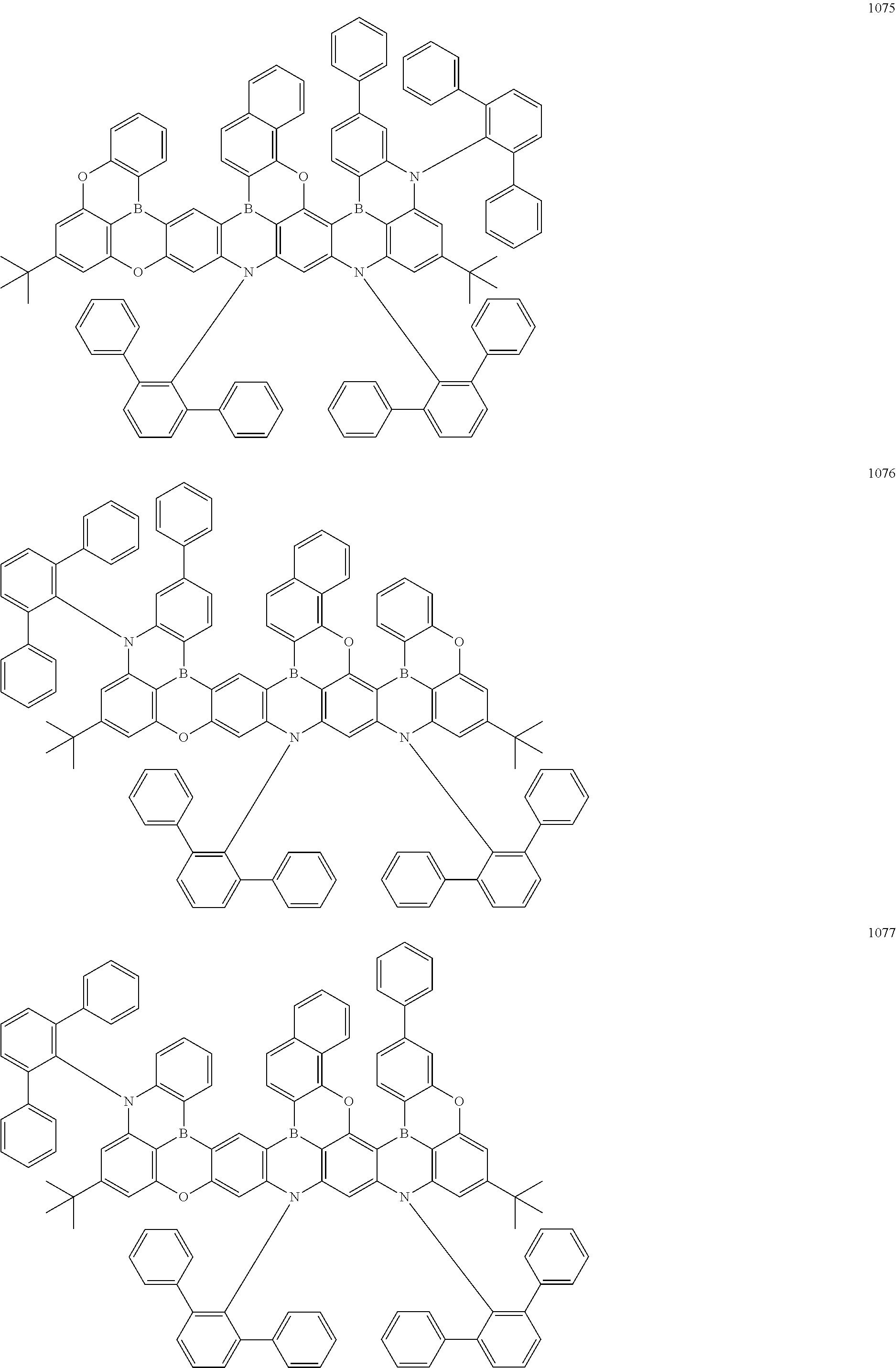

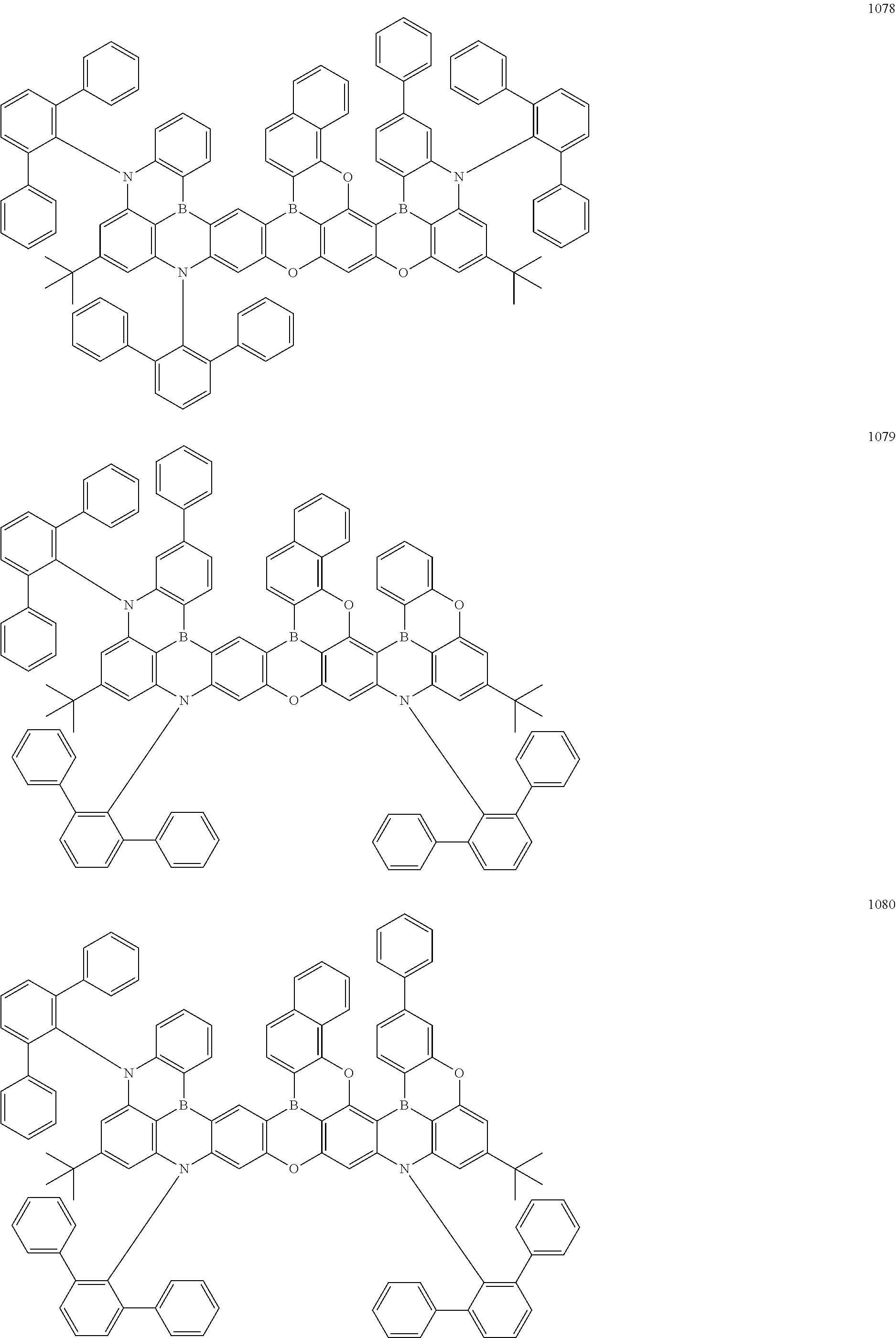

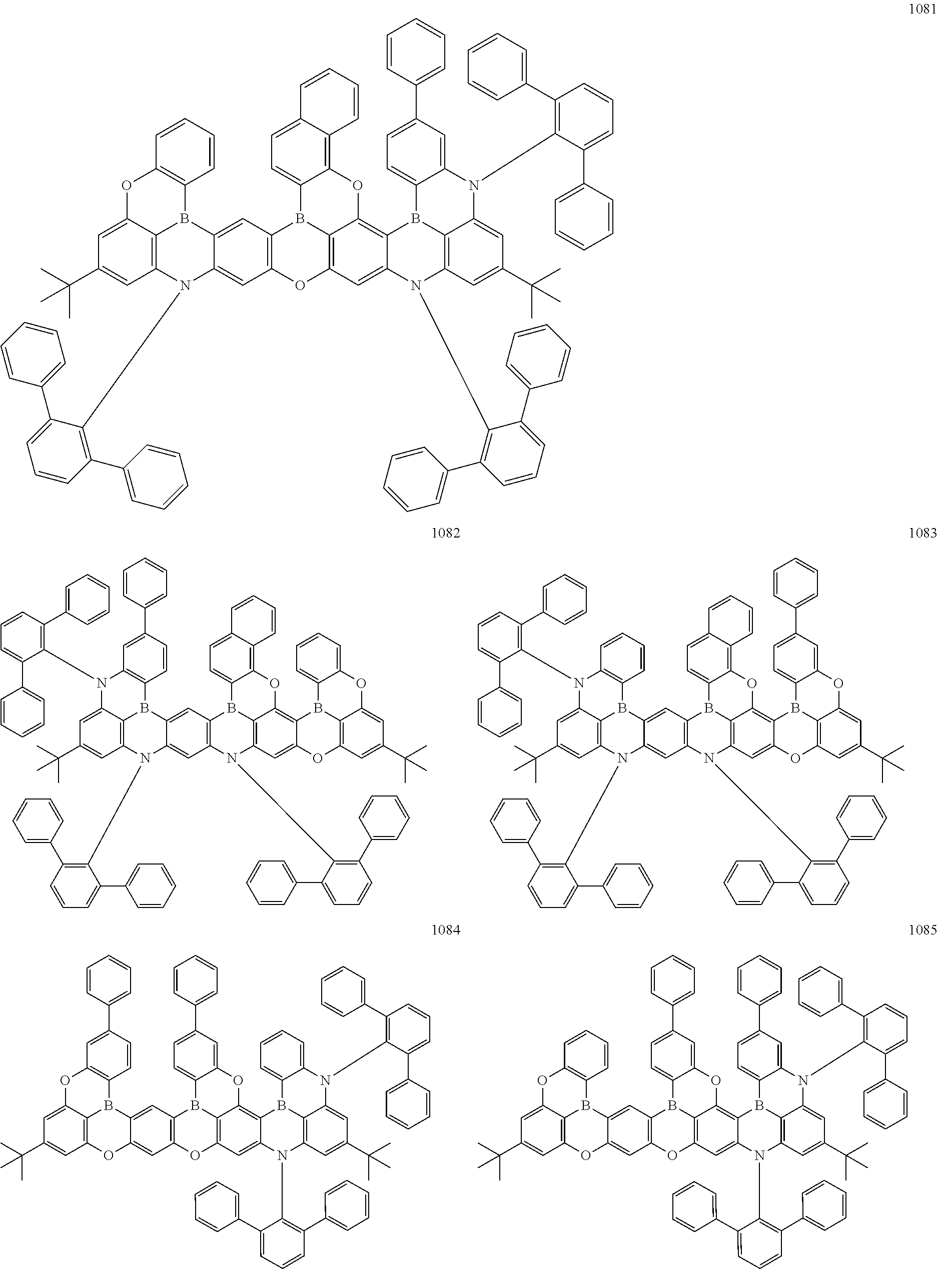

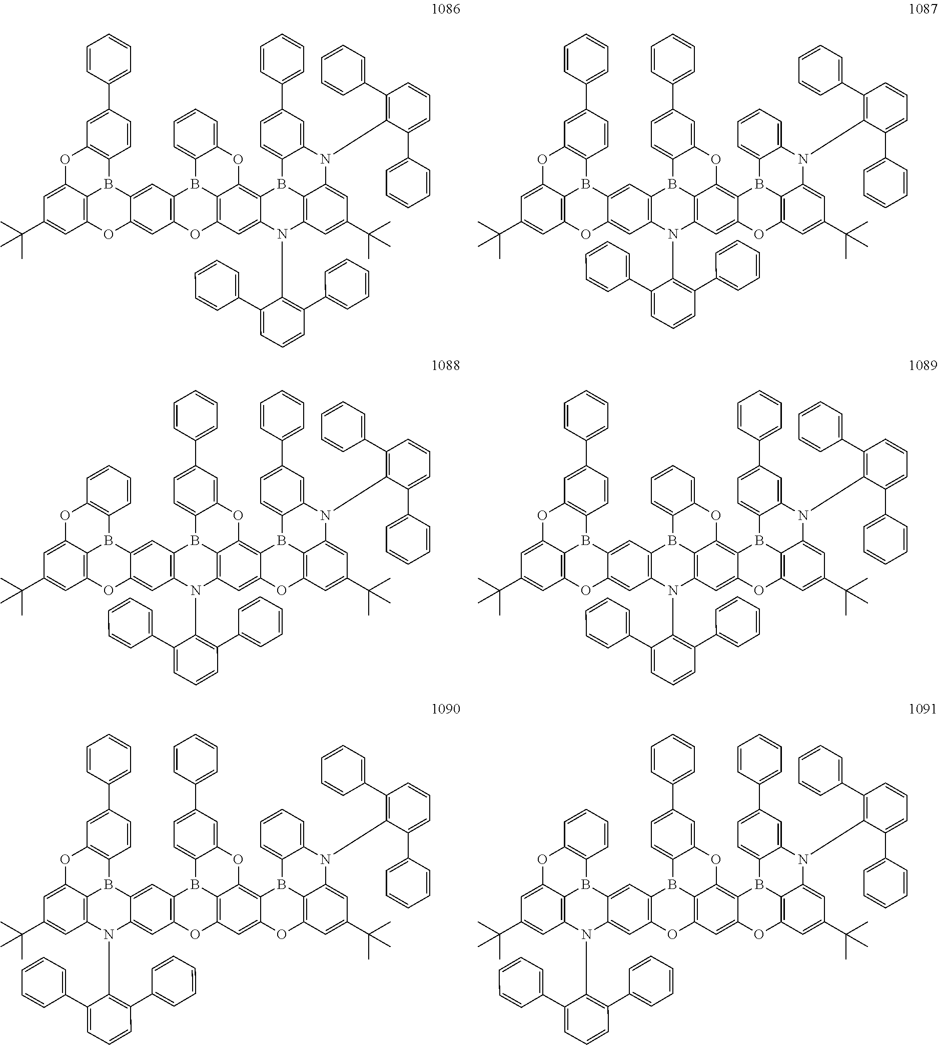

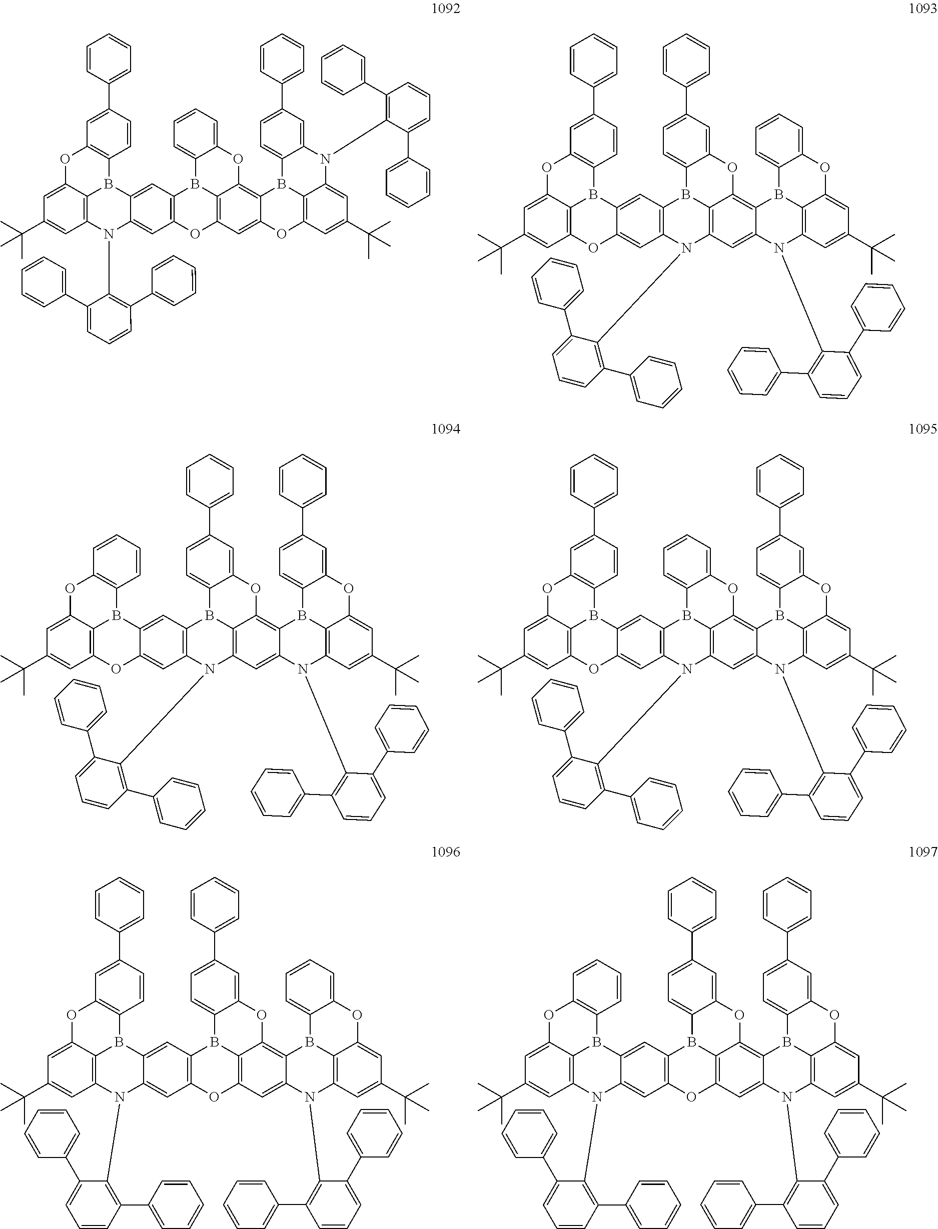

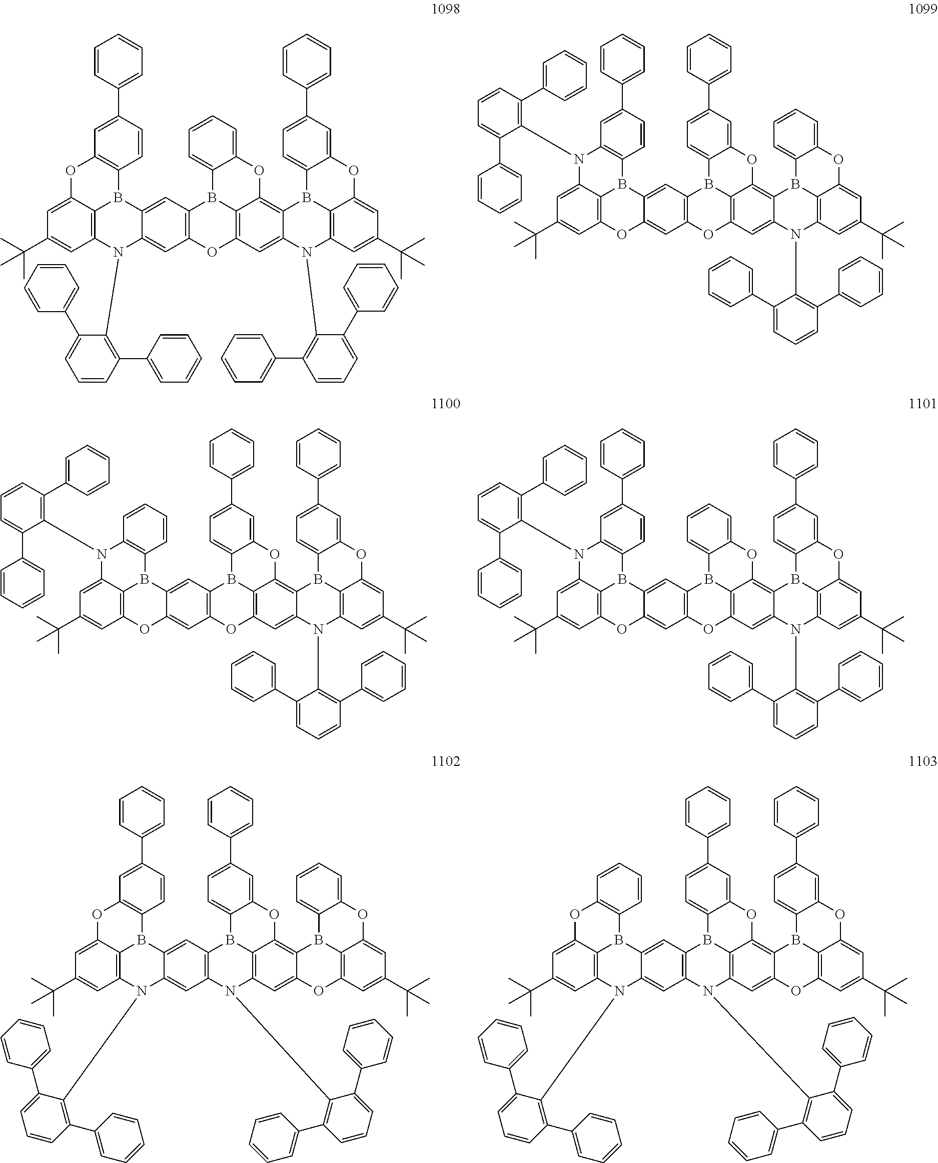

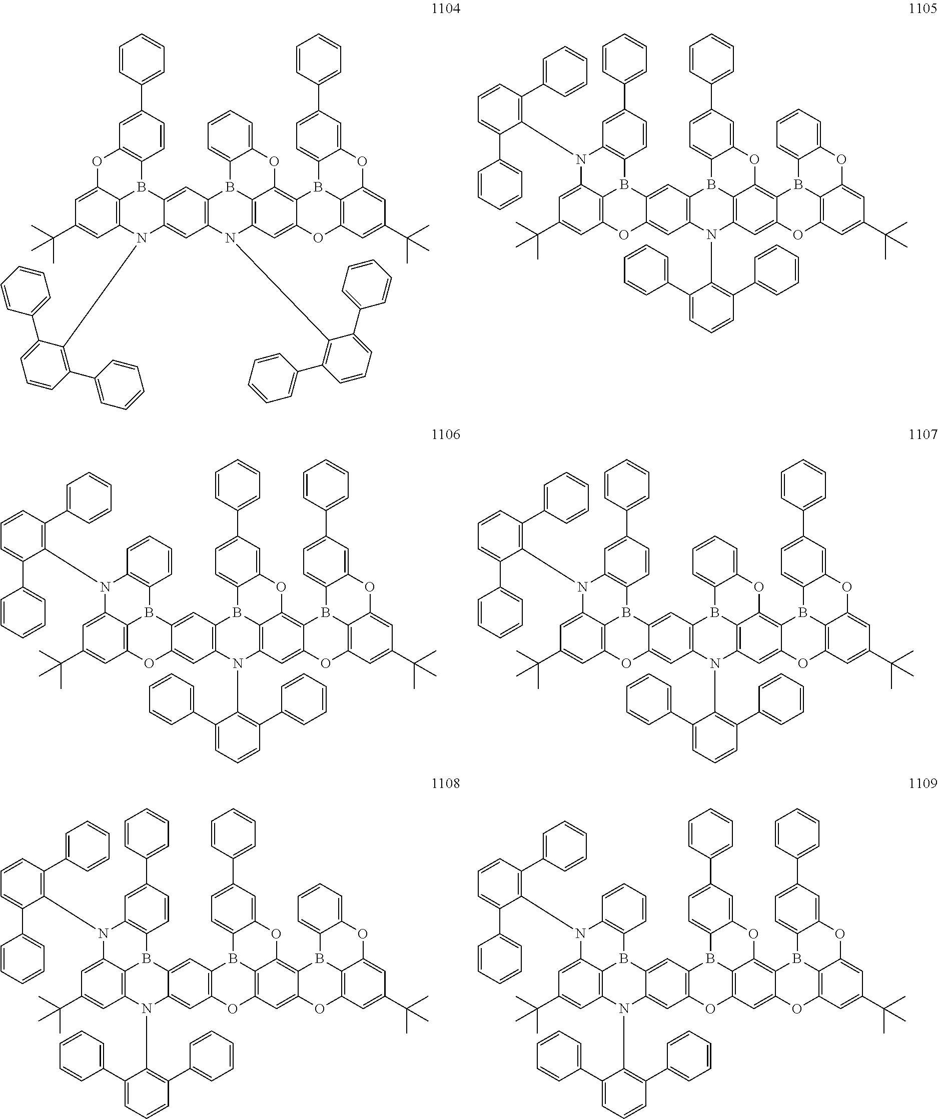

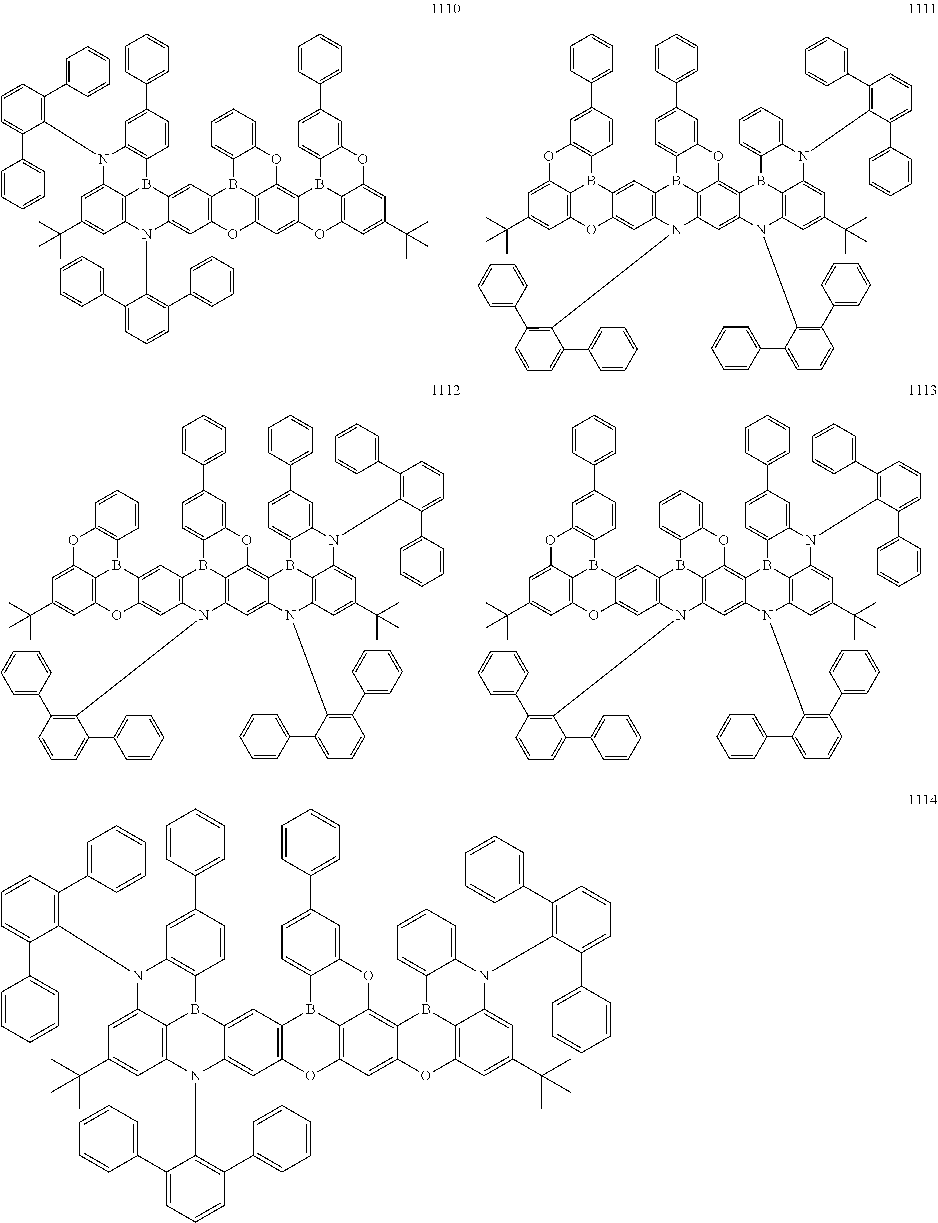

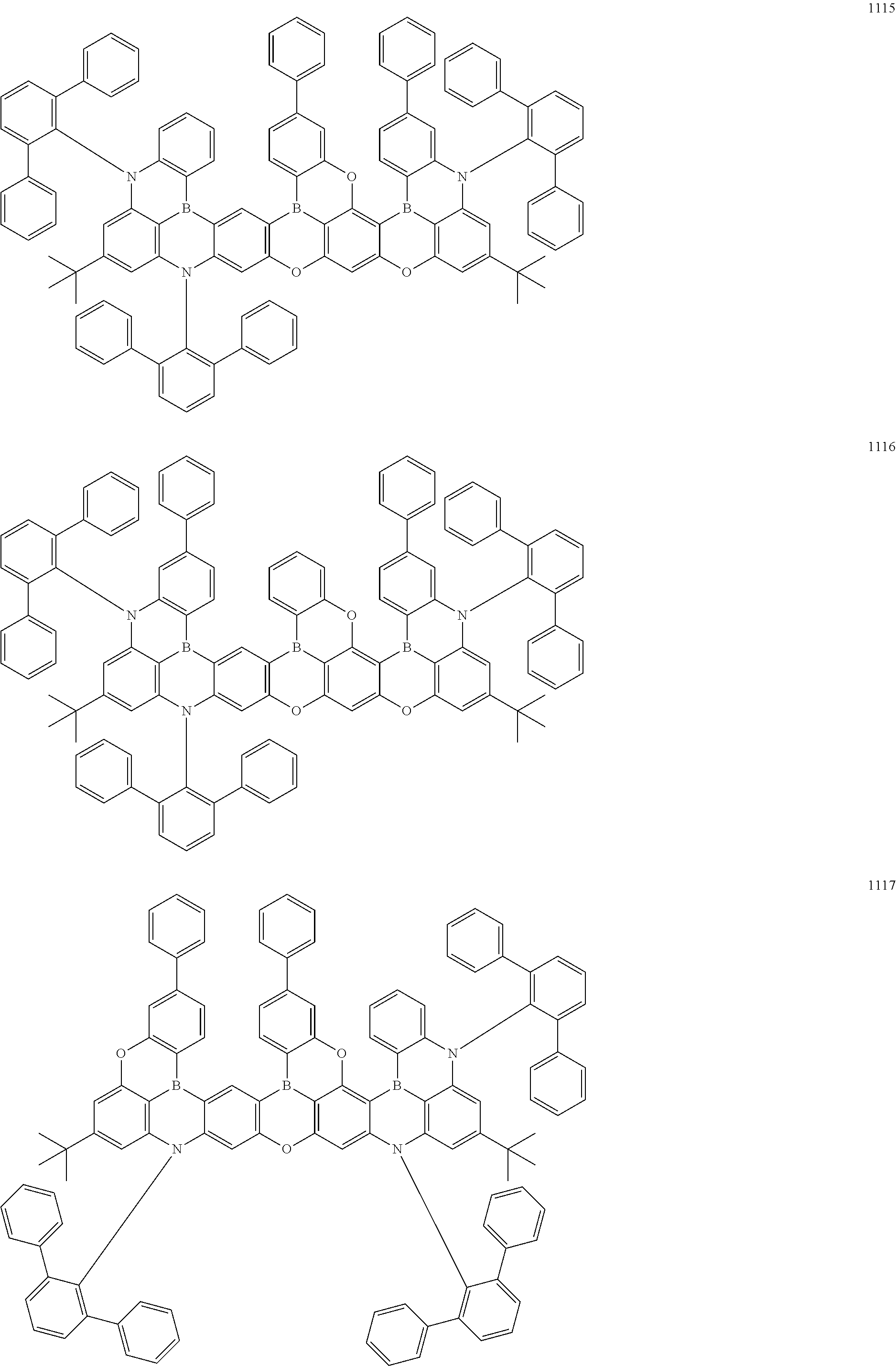

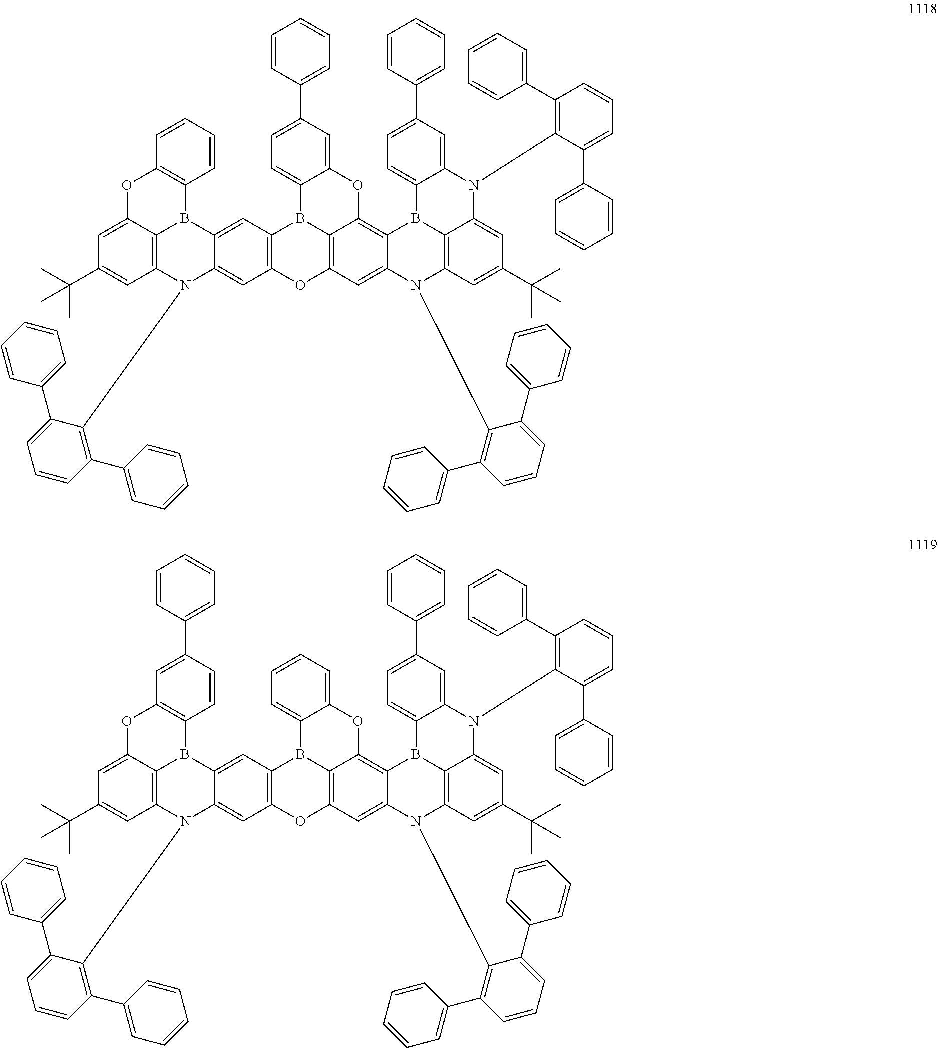

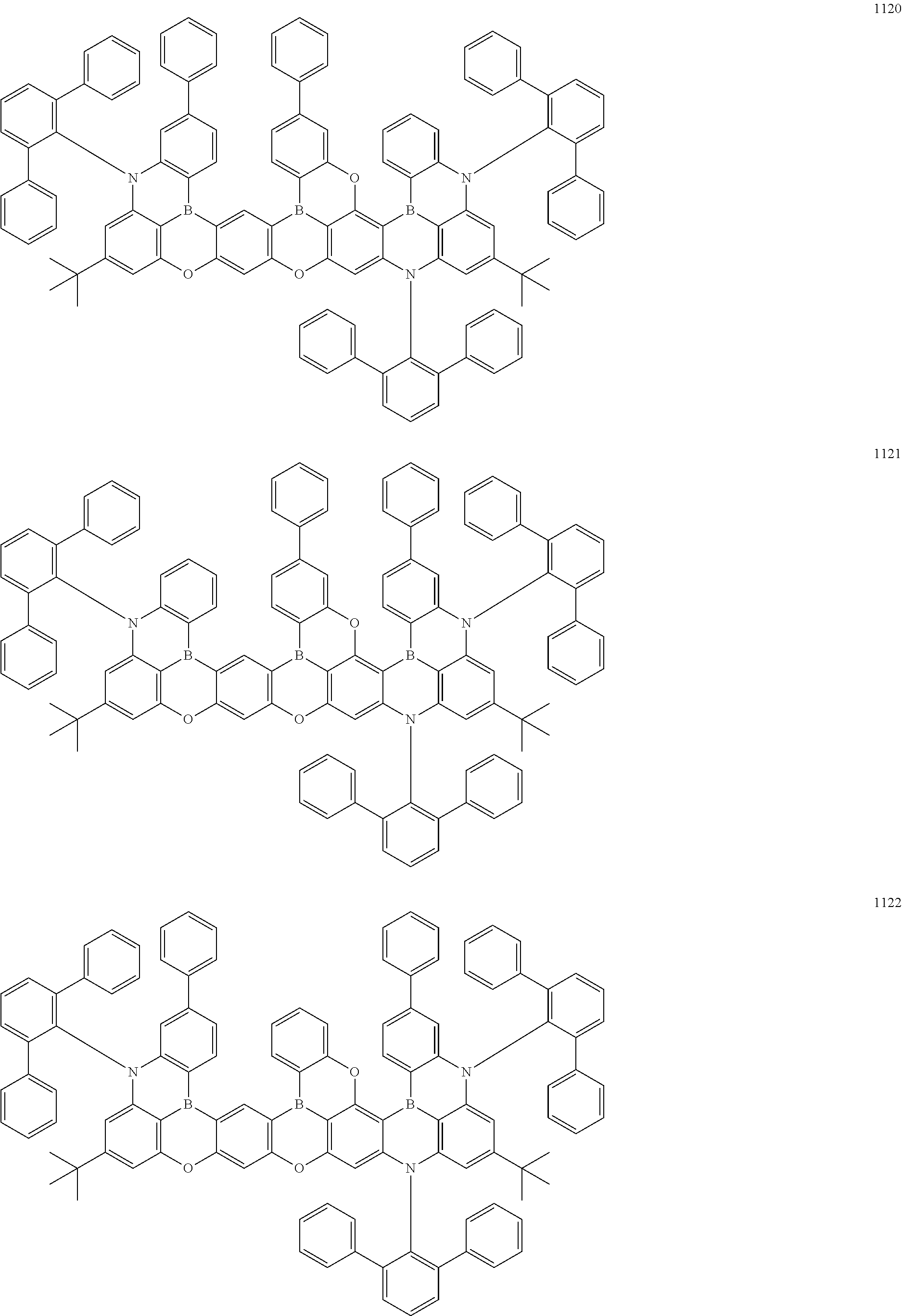

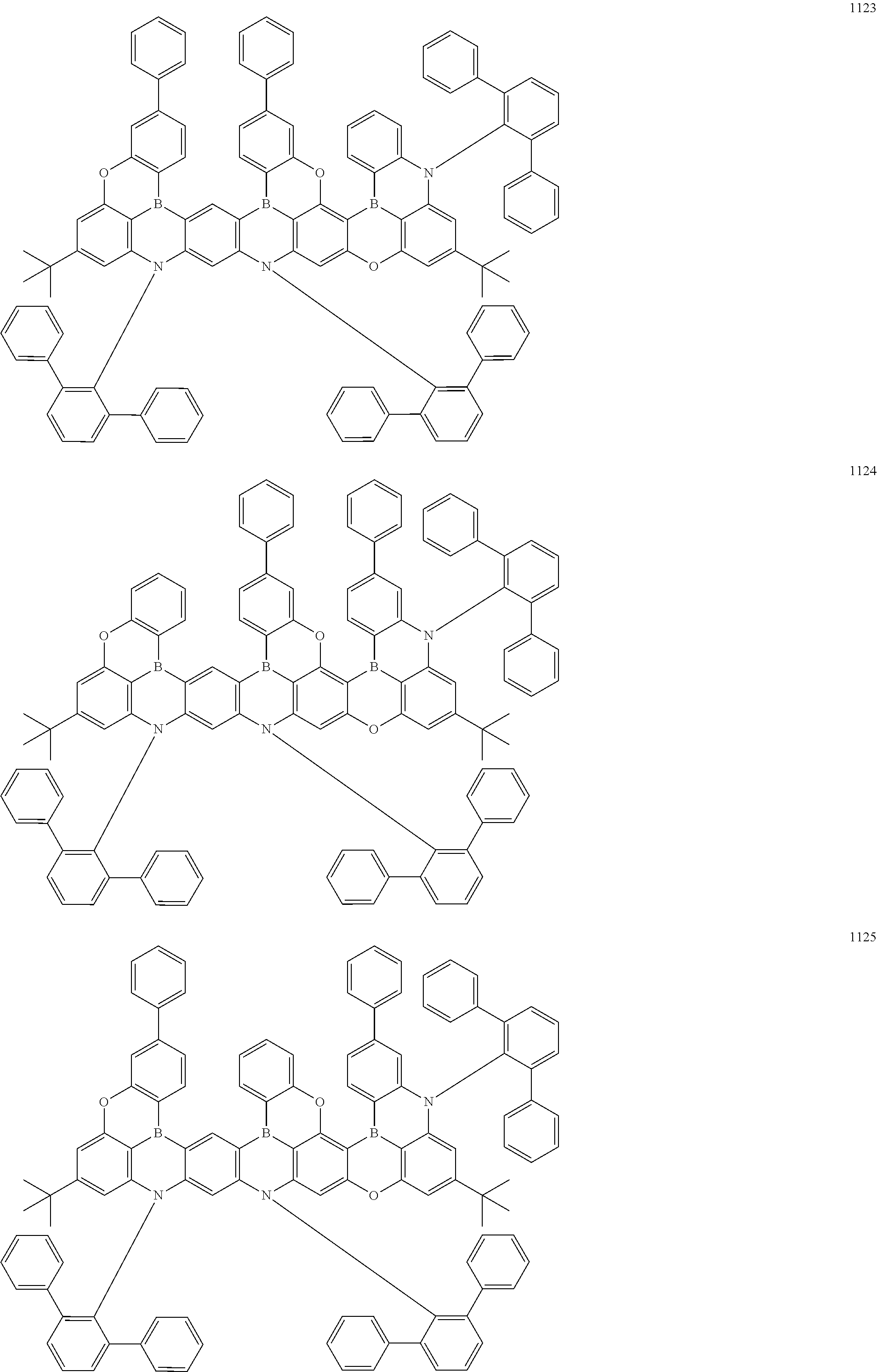

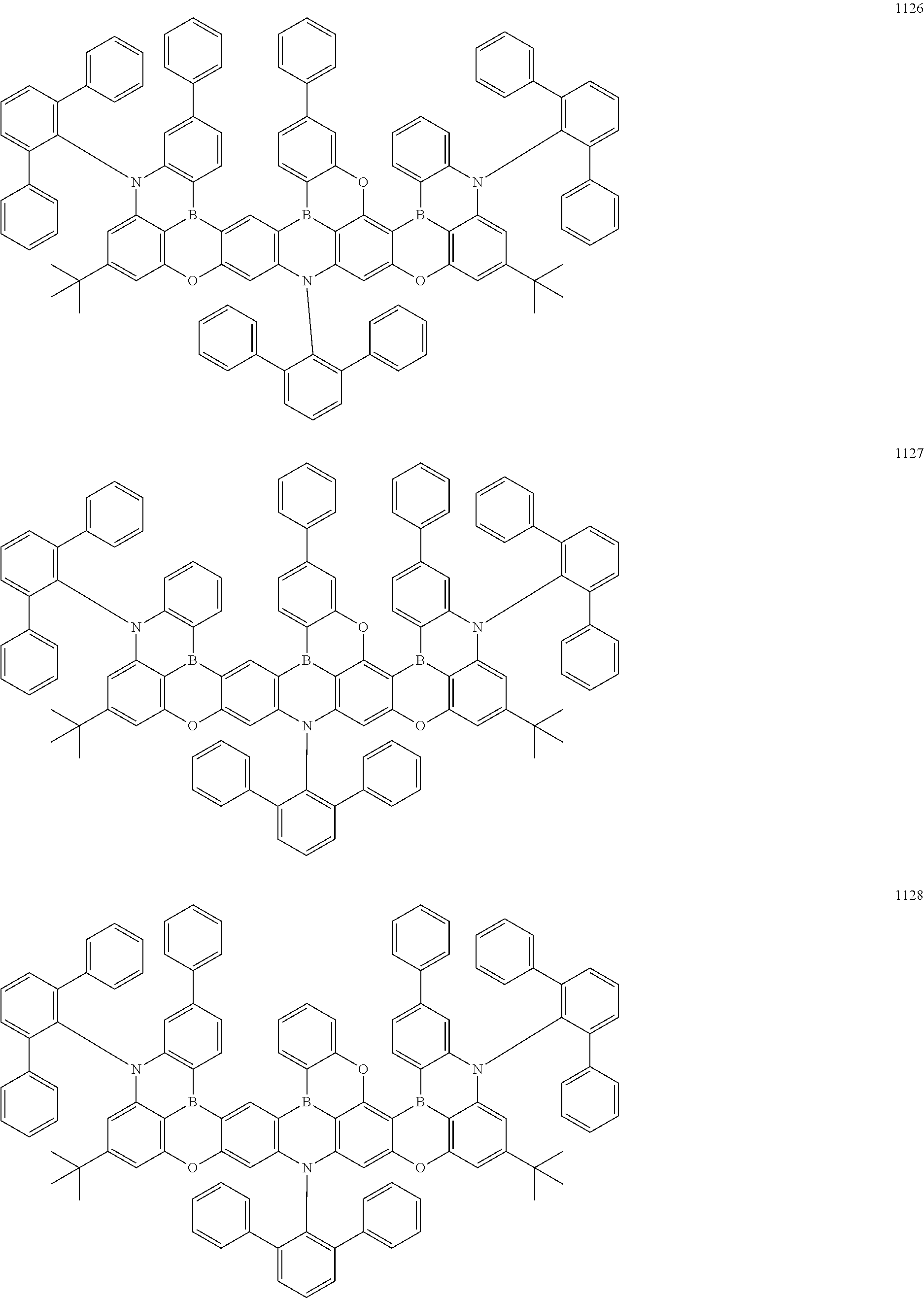

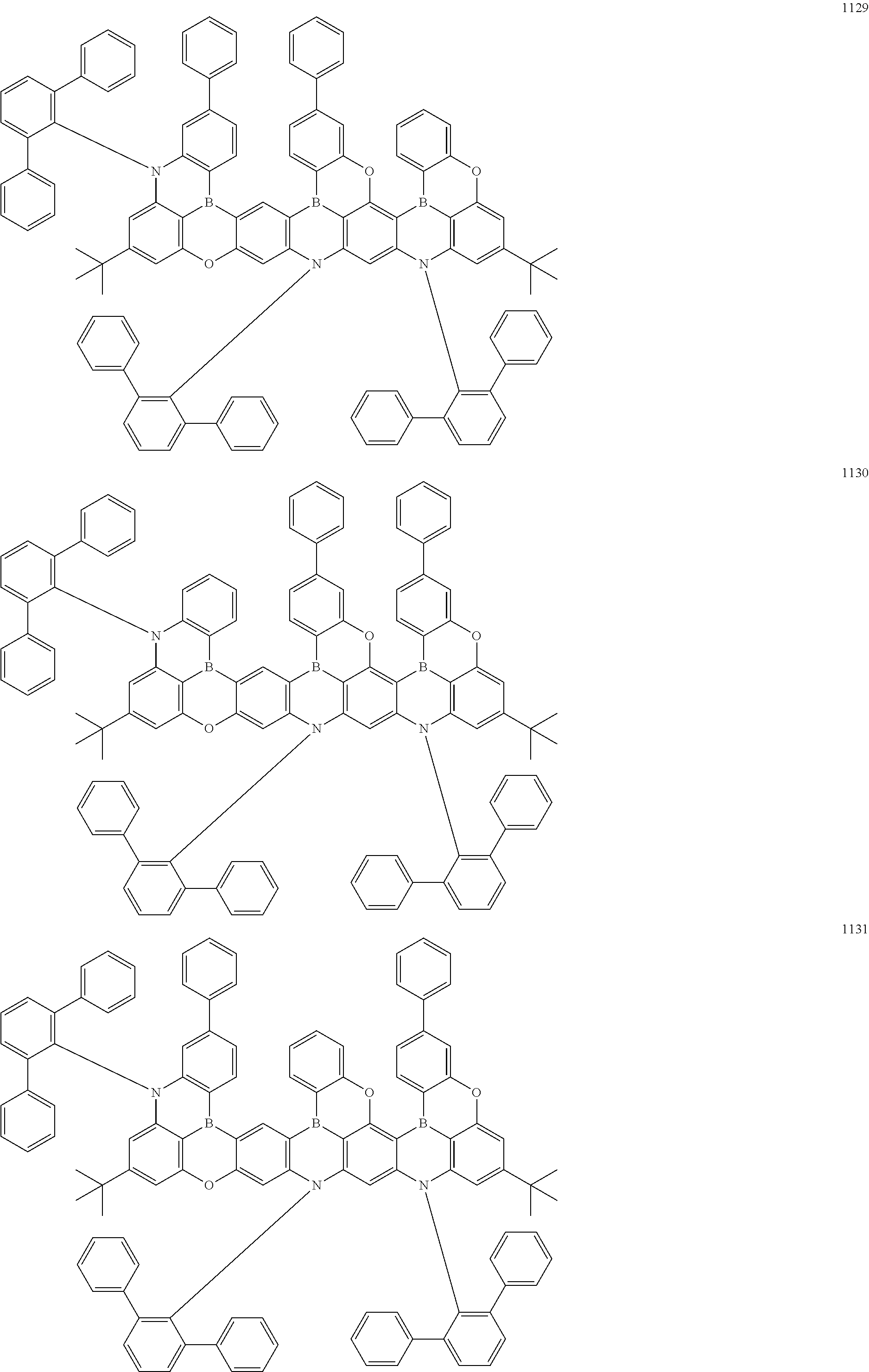

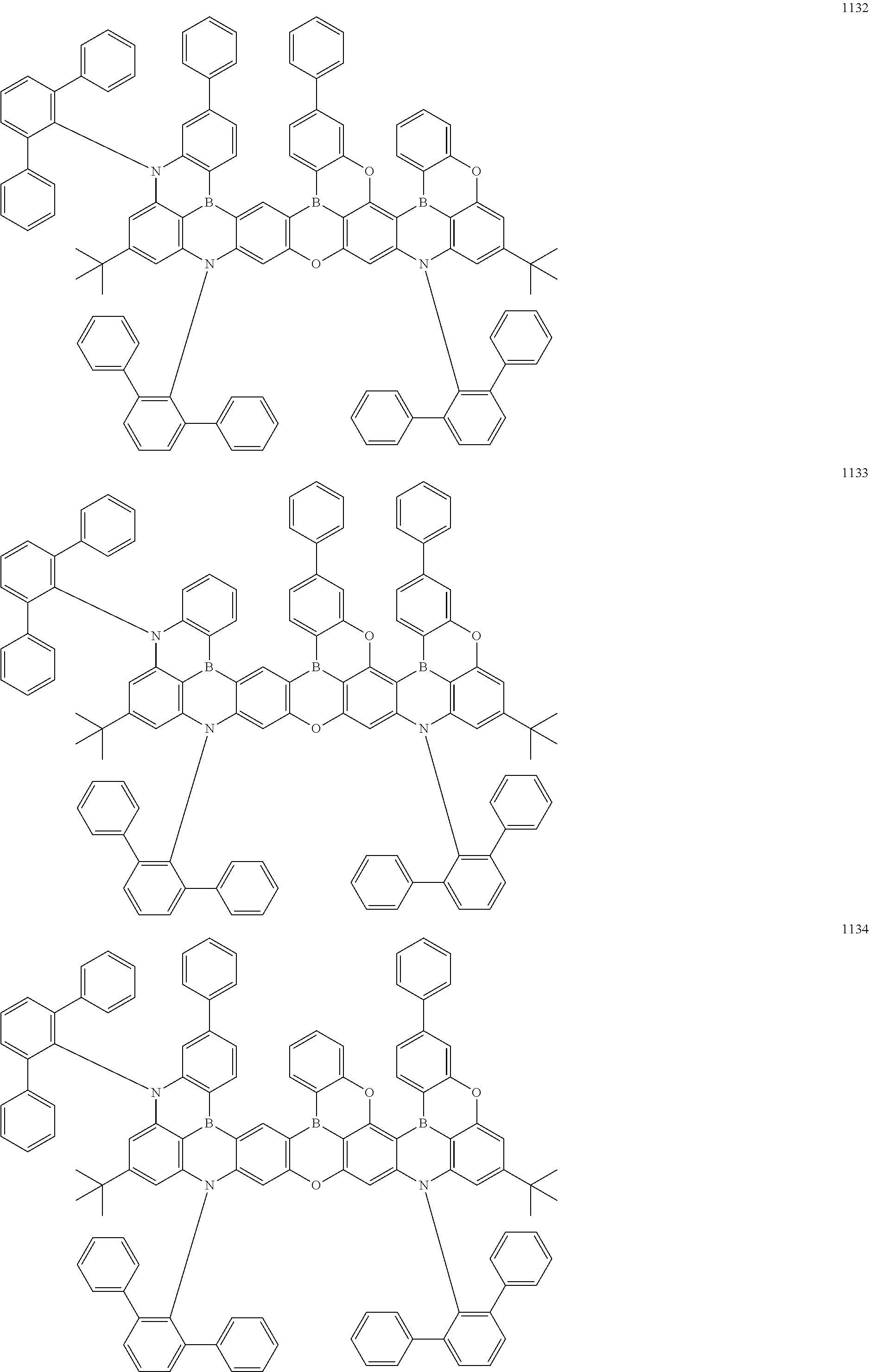

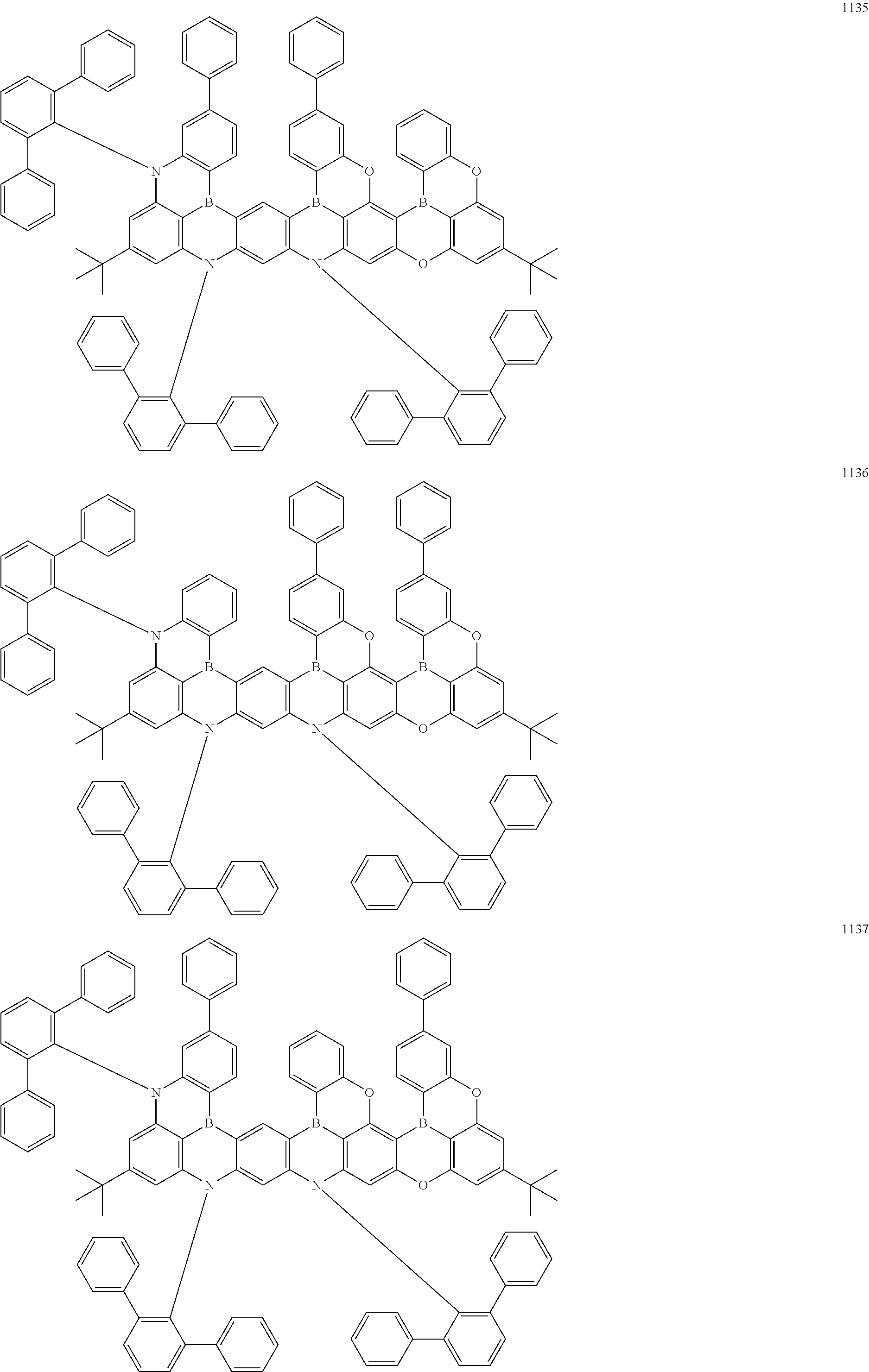

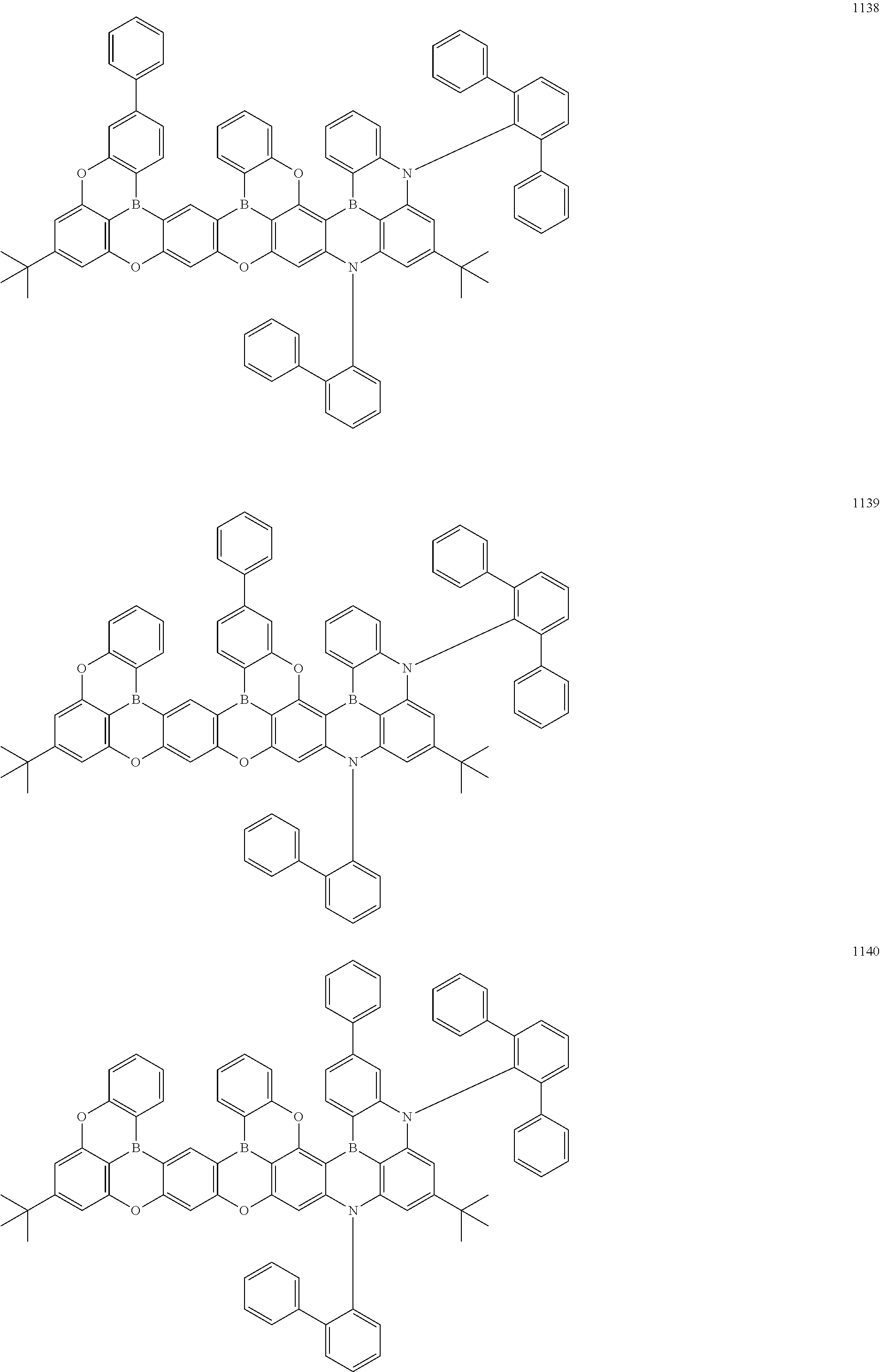

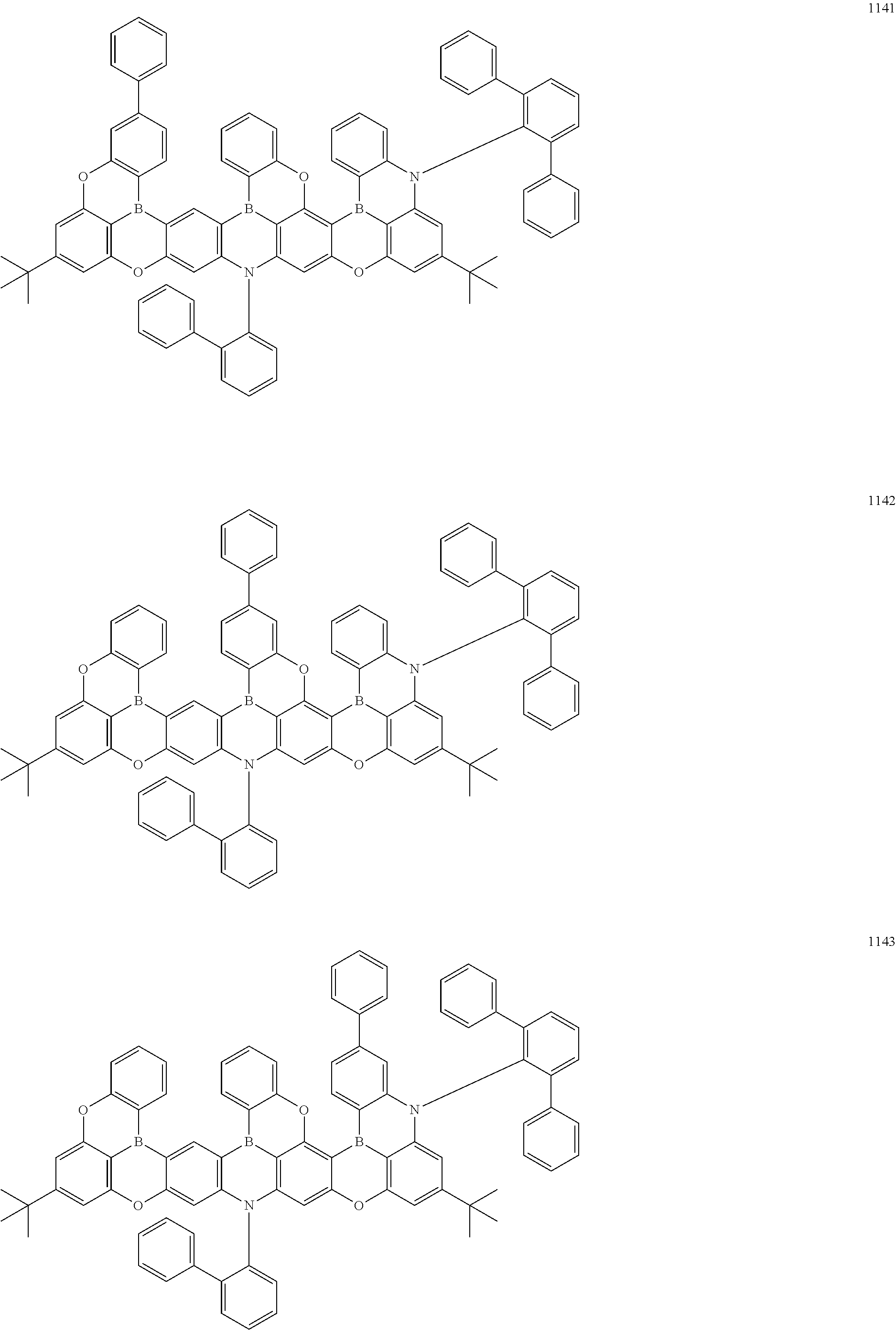 [SMILES: CC(C)(C)c1cc2c3c(c1)Oc1cc4c(cc1B3c1ccc(-c3ccccc3)cc1O2)B1c2ccccc2Oc2c3c(cc(c21)N4c1ccccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccc(-c3ccccc3)cc2Oc2c3c(cc(c21)N4c1ccccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccccc2Oc2c3c(cc(c21)N4c1ccccc1-c1ccccc1)Oc1cc(C(C)(C)C)cc2c1B3c1ccc(-c3ccccc3)cc1N2c1c(-c2ccccc2)cccc1-c1ccccc1]

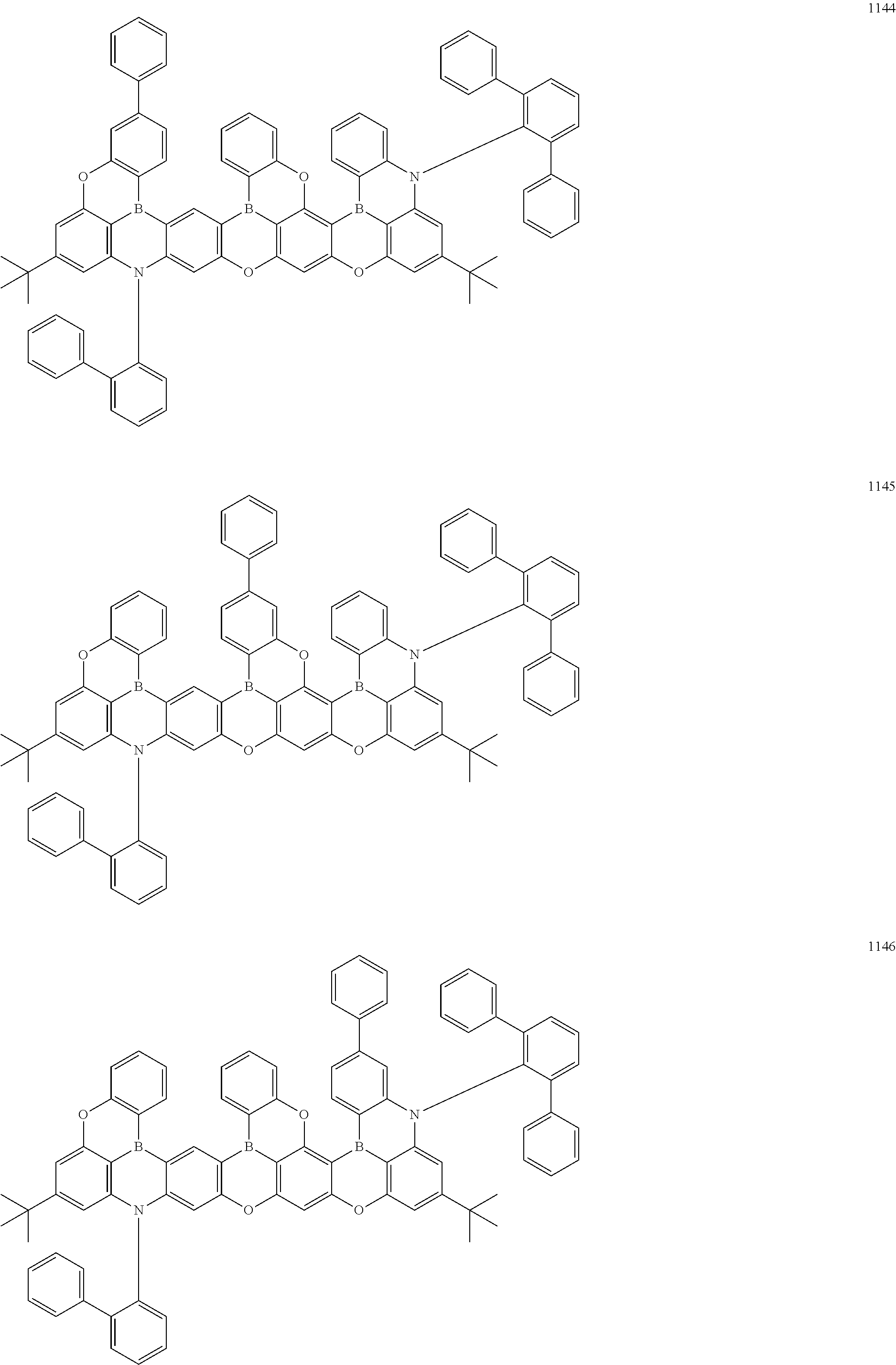 [SMILES: CC(C)(C)c1cc2c3c(c1)N(c1ccccc1-c1ccccc1)c1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)O1)O4 ; CC(C)(C)c1cc2c3c(c1)N(c1ccccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)O1)O4 ; CC(C)(C)c1cc2c3c(c1)N(c1ccccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)O1)O4]

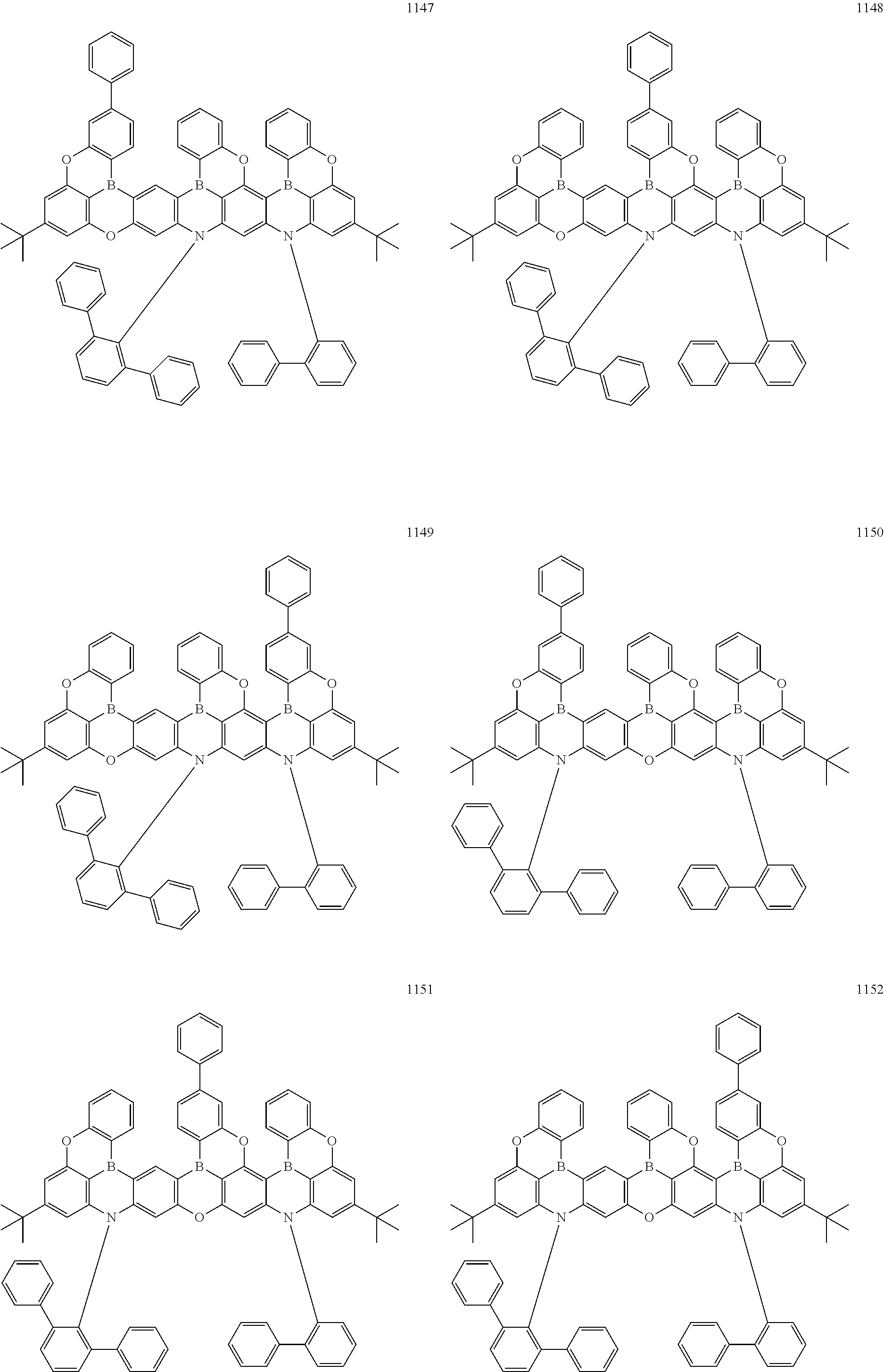

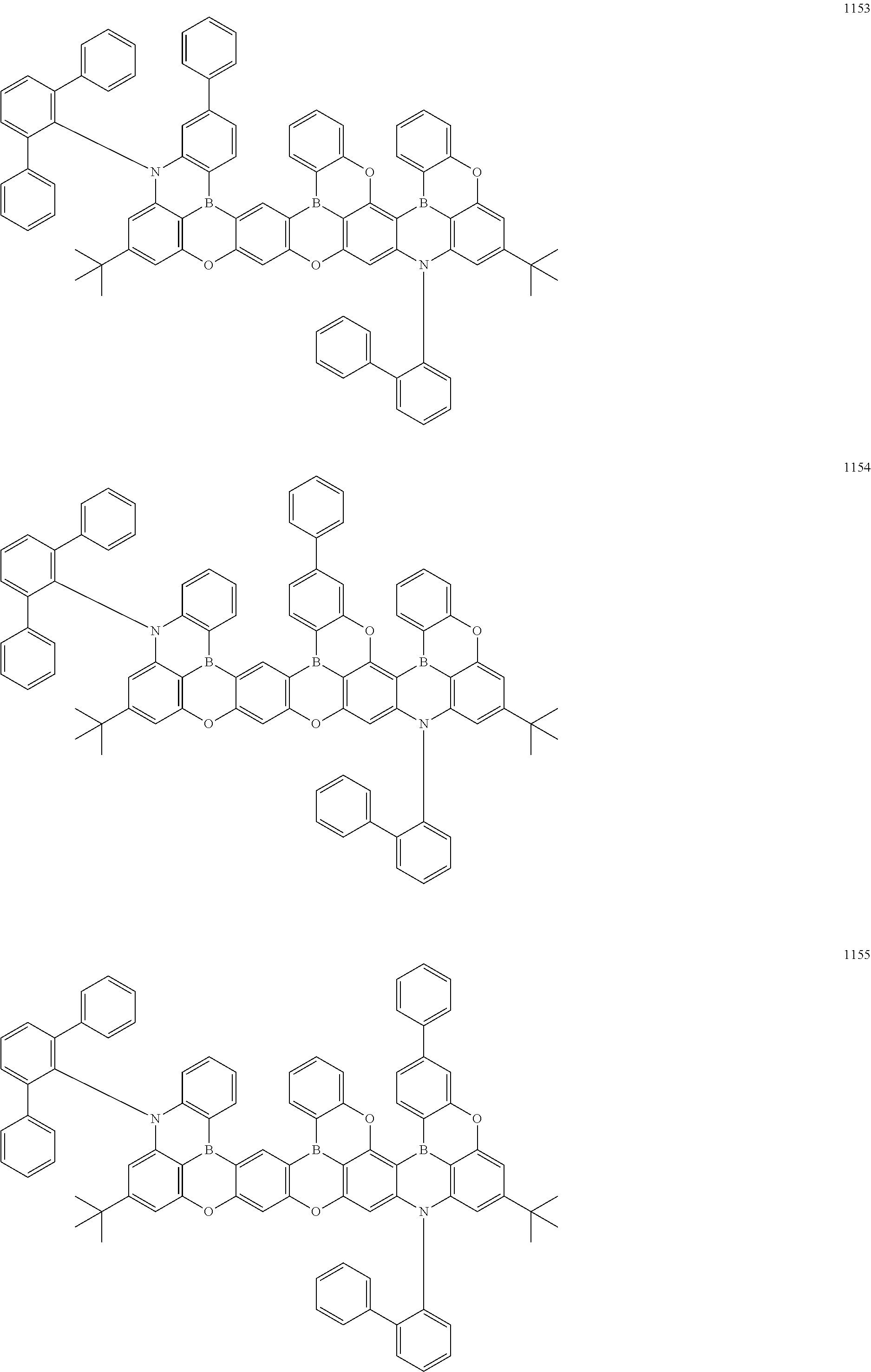 [SMILES: CC(C)(C)c1cc2c3c(c1)N(c1ccccc1-c1ccccc1)c1cc4c5c(c1B3c1ccccc1O2)Oc1ccccc1B5c1cc2c(cc1O4)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1ccccc1-c1ccccc1)c1cc4c5c(c1B3c1ccccc1O2)Oc1cc(-c2ccccc2)ccc1B5c1cc2c(cc1O4)Oc1cc(C(C)(C)C)cc3c1B2c1ccccc1N3c1c(-c2ccccc2)cccc1-c1ccccc1 ; CC(C)(C)c1cc2c3c(c1)N(c1ccccc1-c1ccccc1)c1cc4c5c(c1B3c1ccc(-c3ccccc3)cc1O2)Oc1ccccc1B5c1cc2c(cc1O4)Oc1cc(C(C)(C)C)cc3c1B2c1ccccc1N3c1c(-c2ccccc2)cccc1-c1ccccc1]

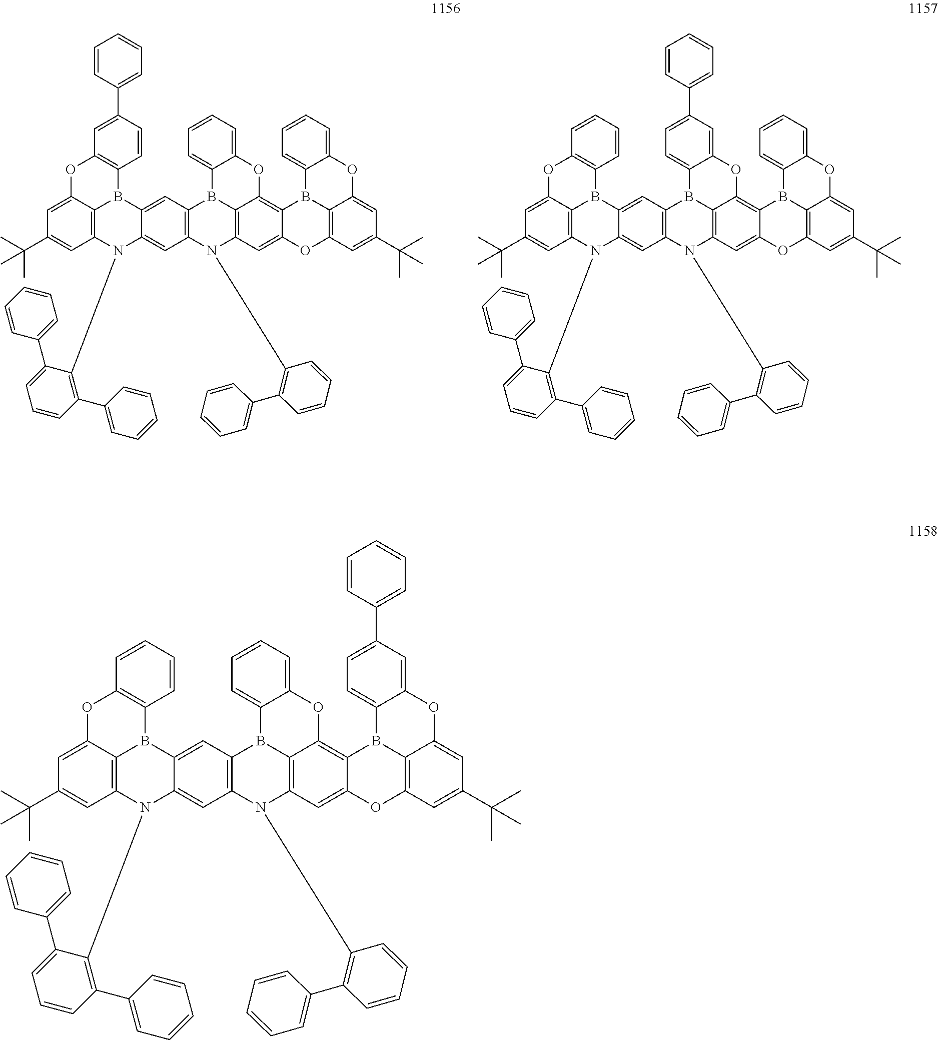 [SMILES: CC(C)(C)c1cc2c3c(c1)Oc1cc4c5c(c1B3c1ccccc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-c2ccccc2)cc1O3 ; CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)N(c1c(-c3ccccc3)cccc1-c1ccccc1)c1cc(C(C)(C)C)cc3c1B2c1ccccc1O3 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccccc1O3]

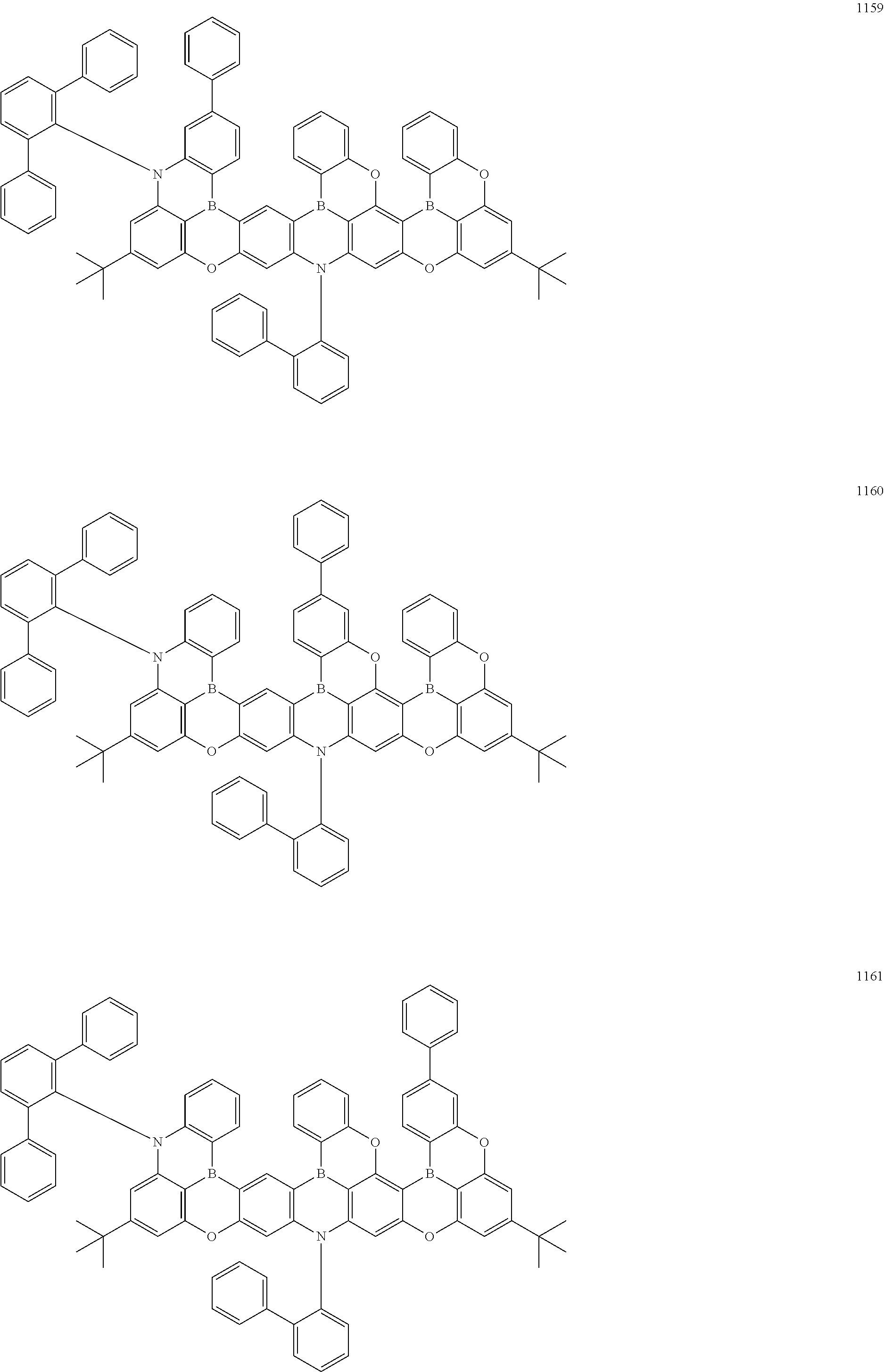 [SMILES: CC(C)(C)c1cc2c3c(c1)Oc1cc4c5c(c1B3c1ccccc1O2)Oc1ccccc1B5c1cc2c(cc1N4c1ccccc1-c1ccccc1)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)Oc1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)Oc1cc(C(C)(C)C)cc3c1B2c1ccccc1N3c1c(-c2ccccc2)cccc1-c1ccccc1]

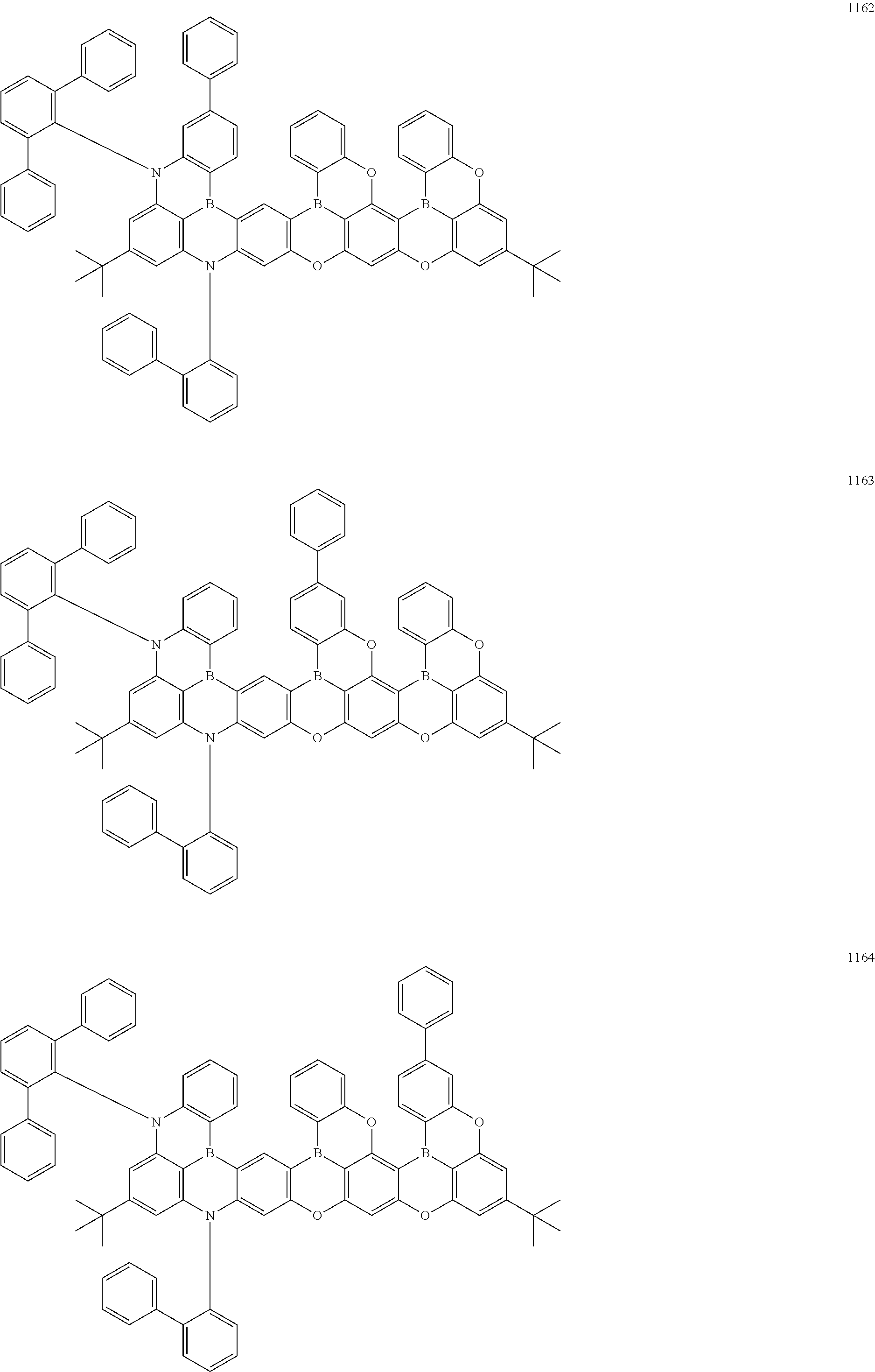 [SMILES: CC(C)(C)c1cc2c3c(c1)Oc1cc4c5c(c1B3c1ccccc1O2)Oc1ccccc1B5c1cc2c(cc1O4)N(c1ccccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1O4)N(c1ccccc1-c1ccccc1)c1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1O4)N(c1ccccc1-c1ccccc1)c1cc(C(C)(C)C)cc3c1B2c1ccccc1N3c1c(-c2ccccc2)cccc1-c1ccccc1]

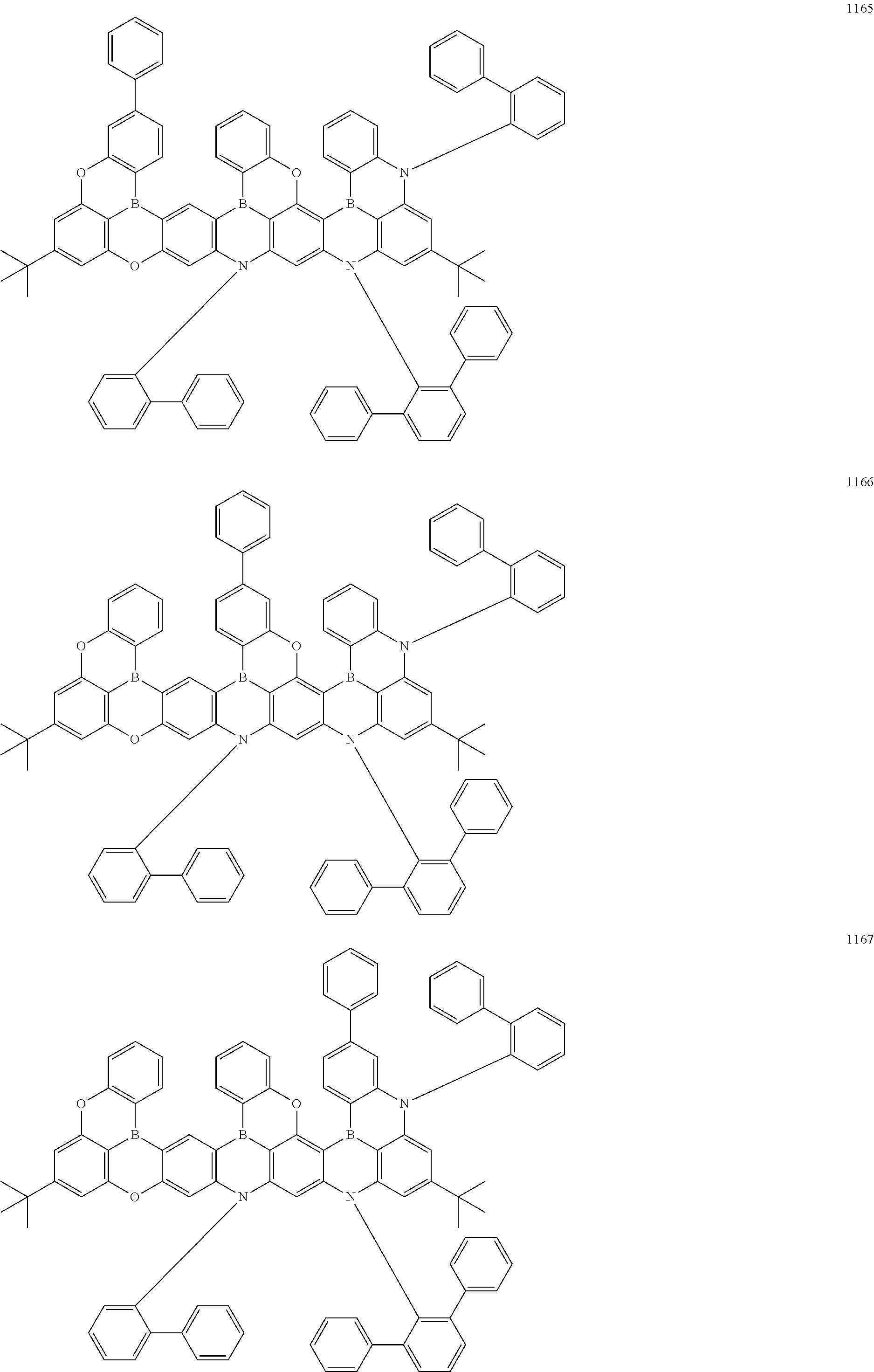

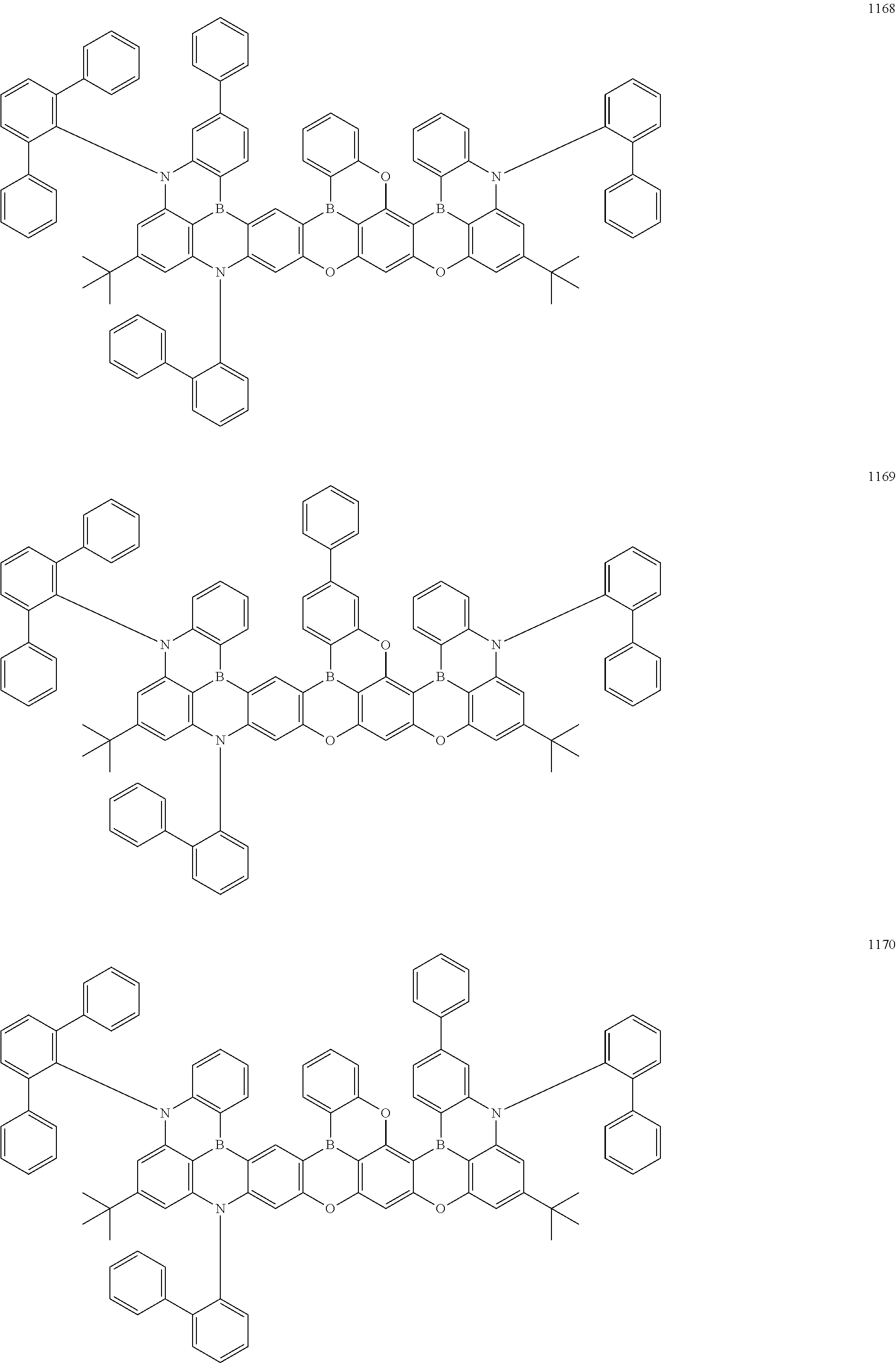

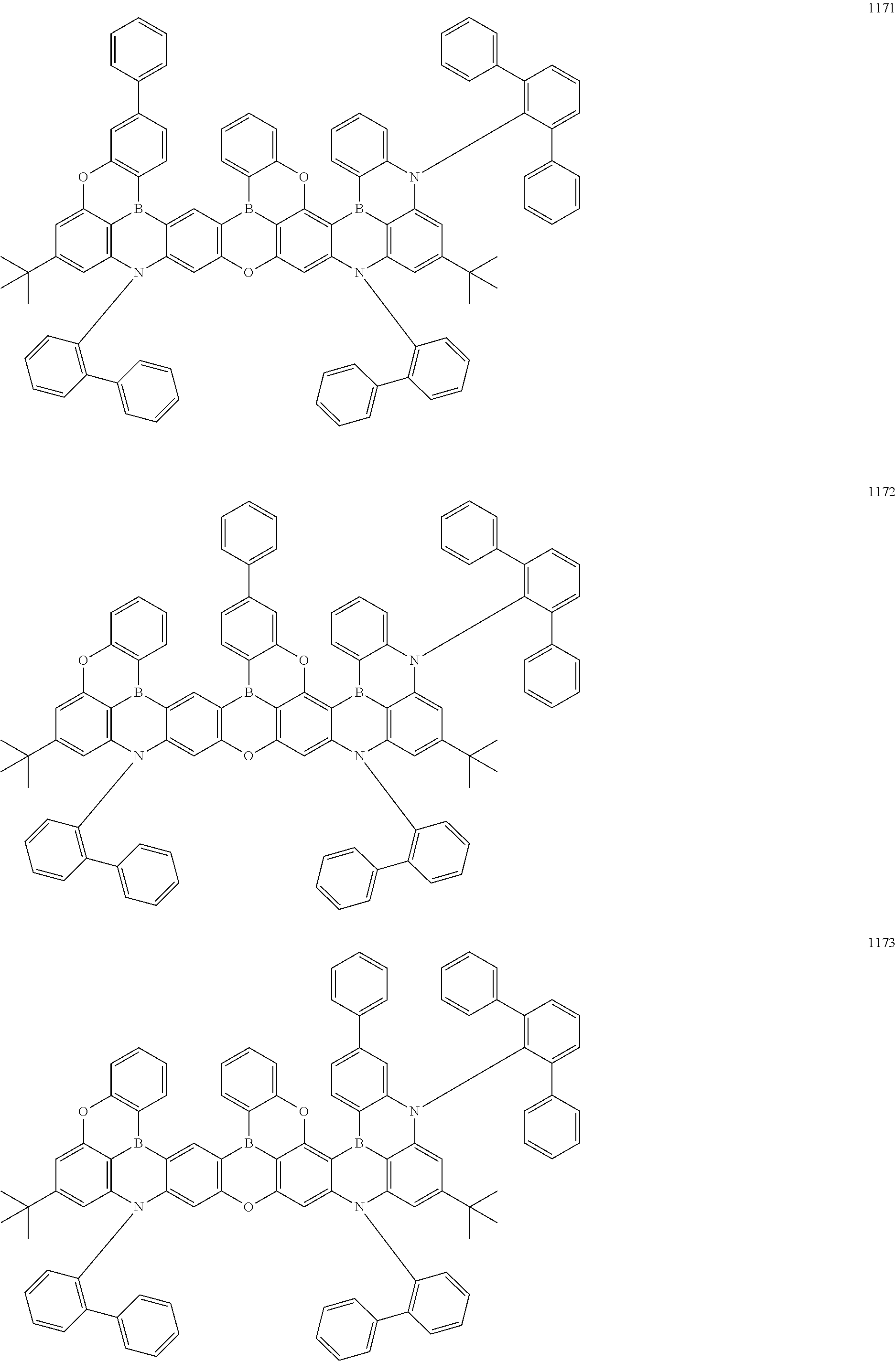

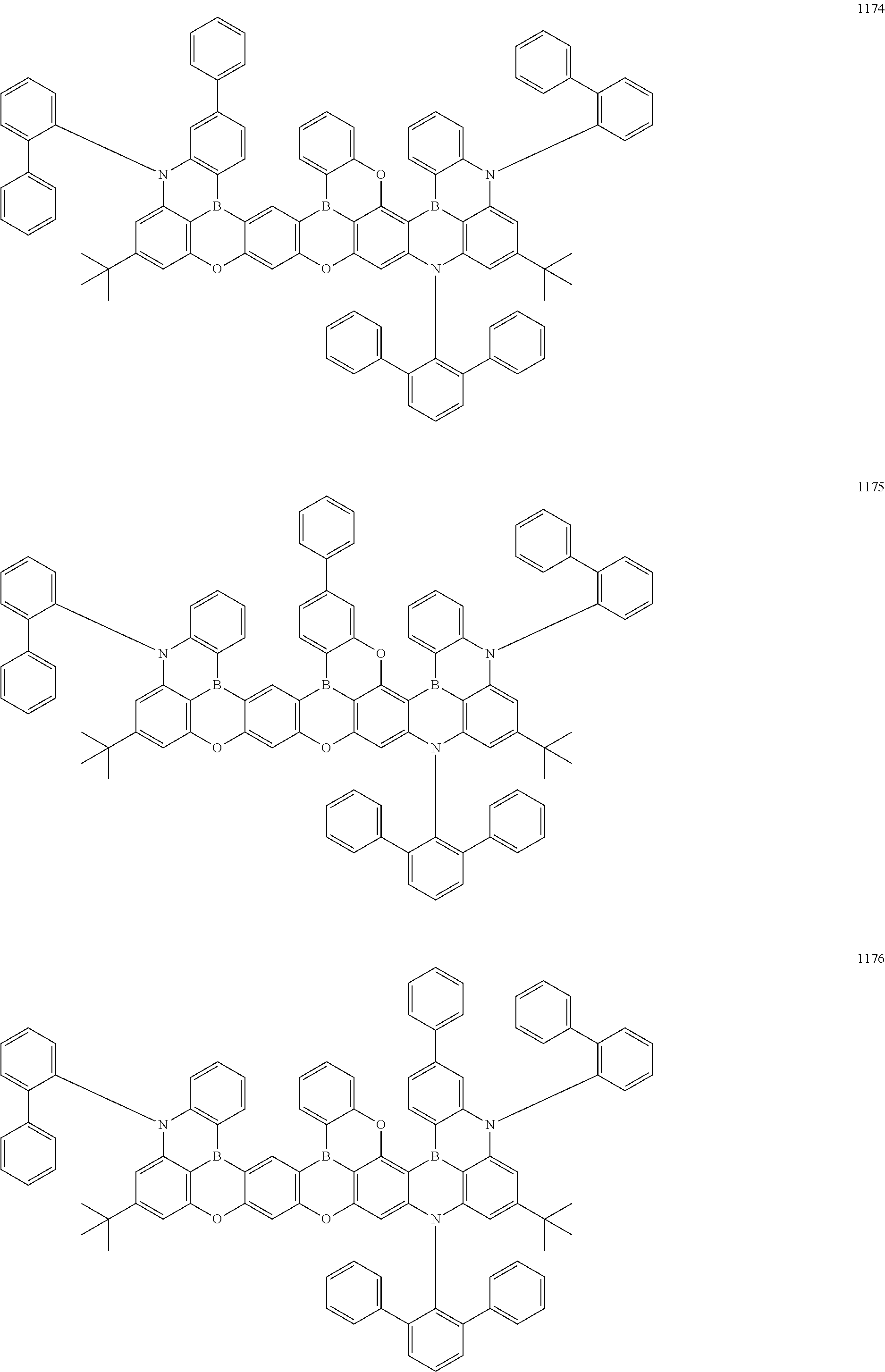

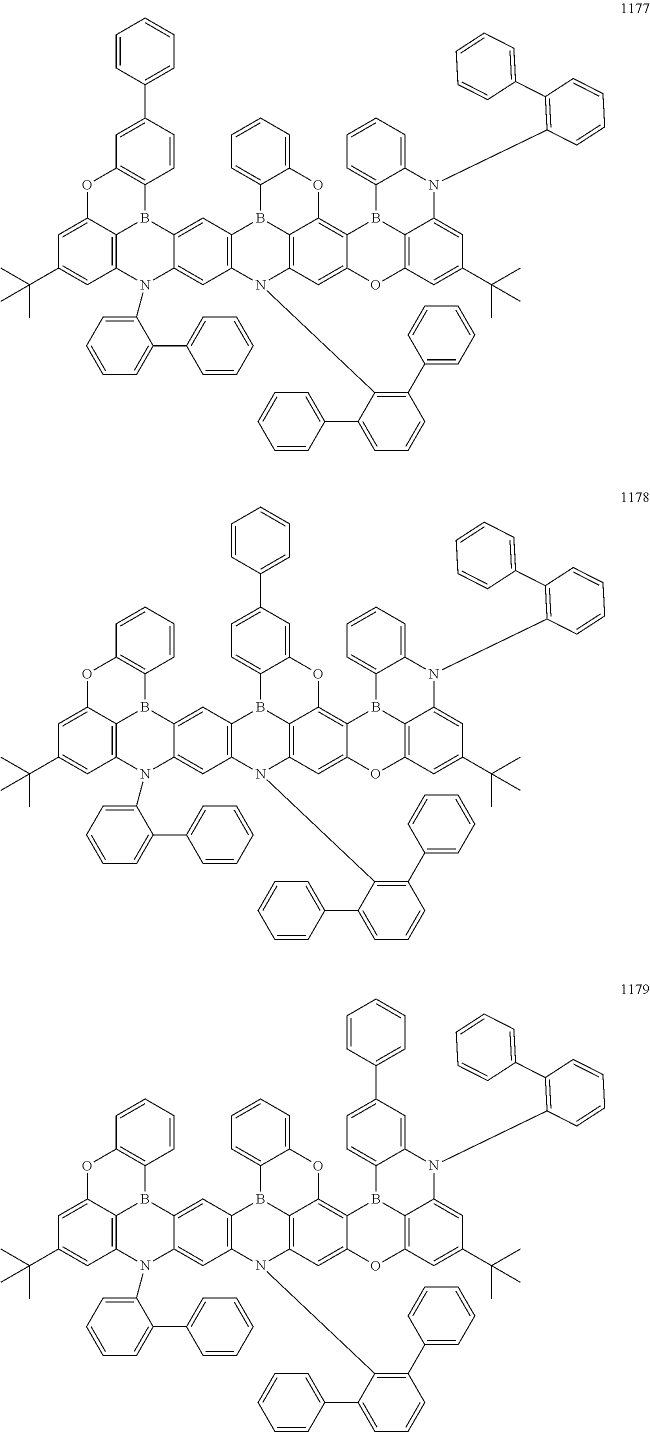

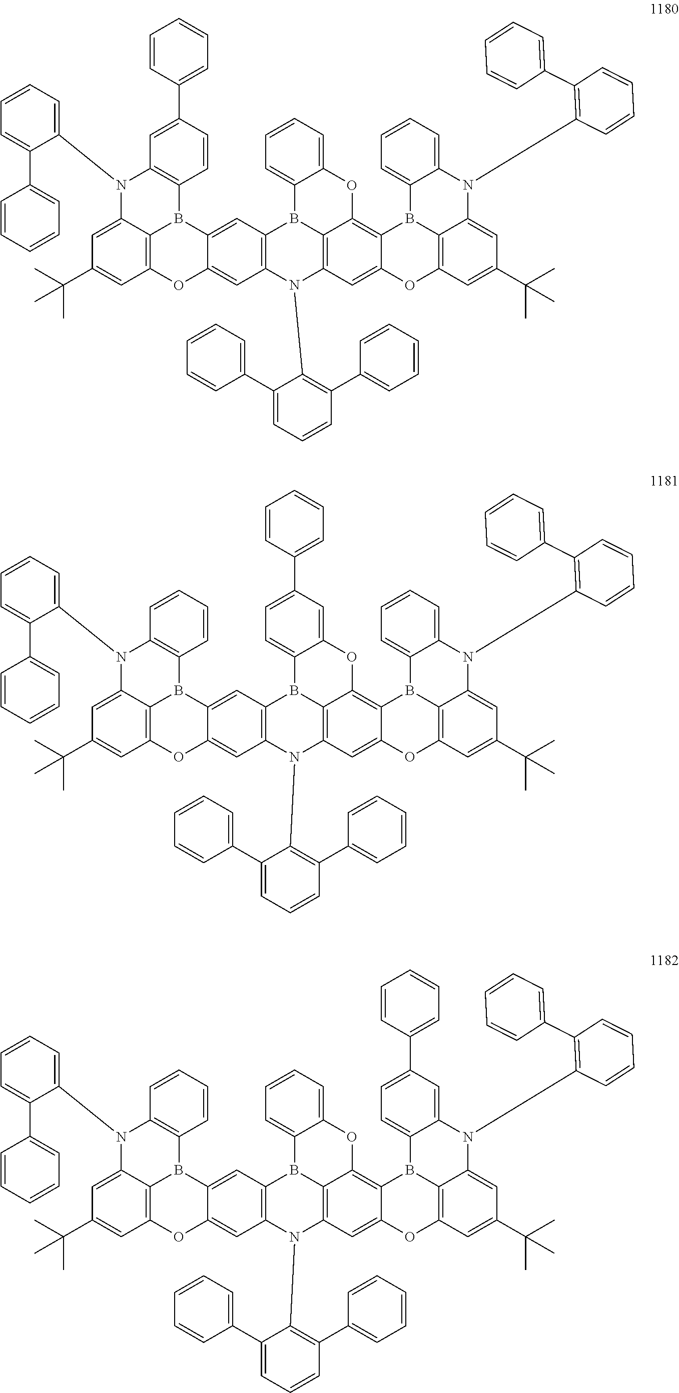

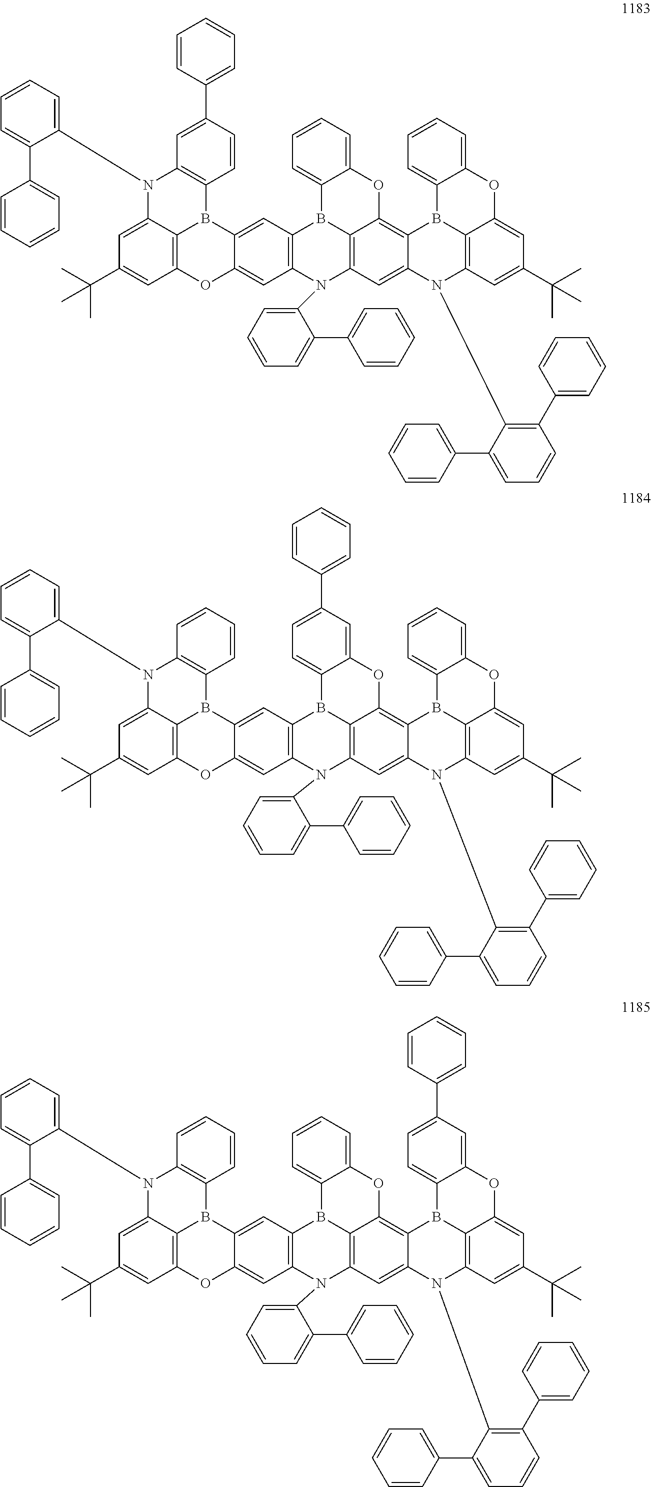

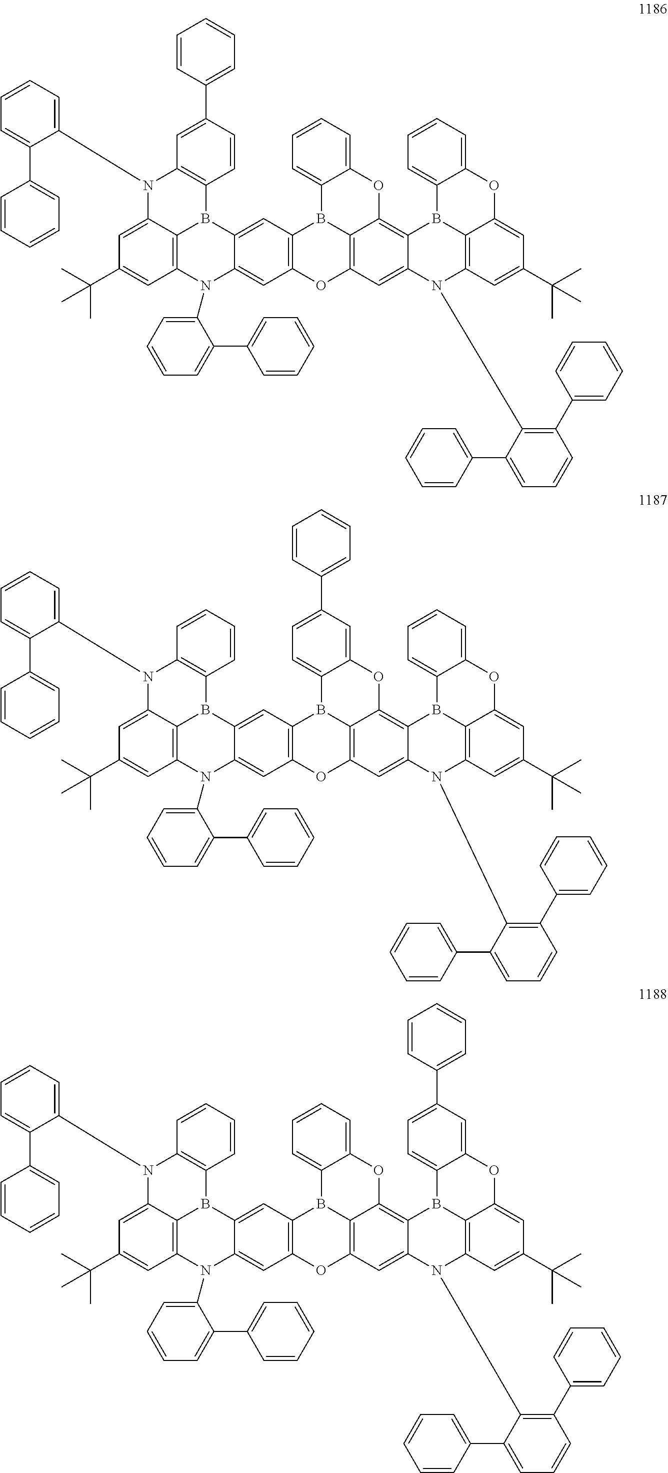

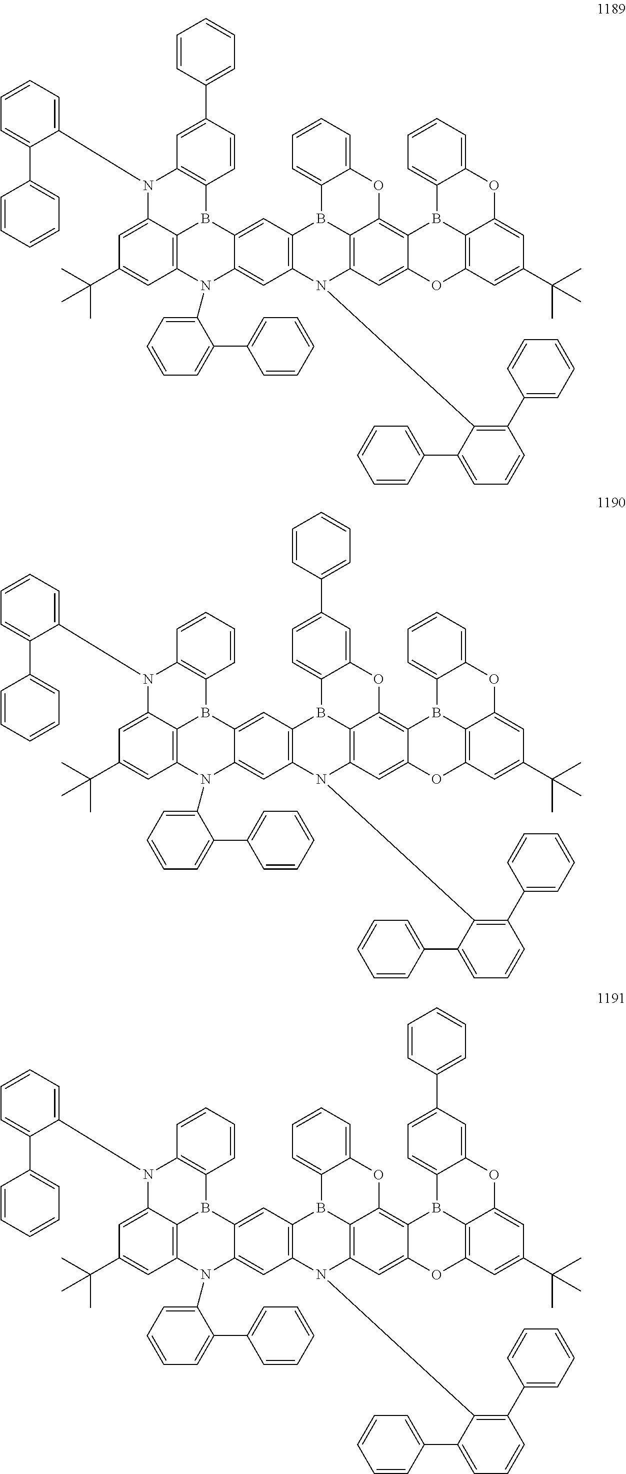

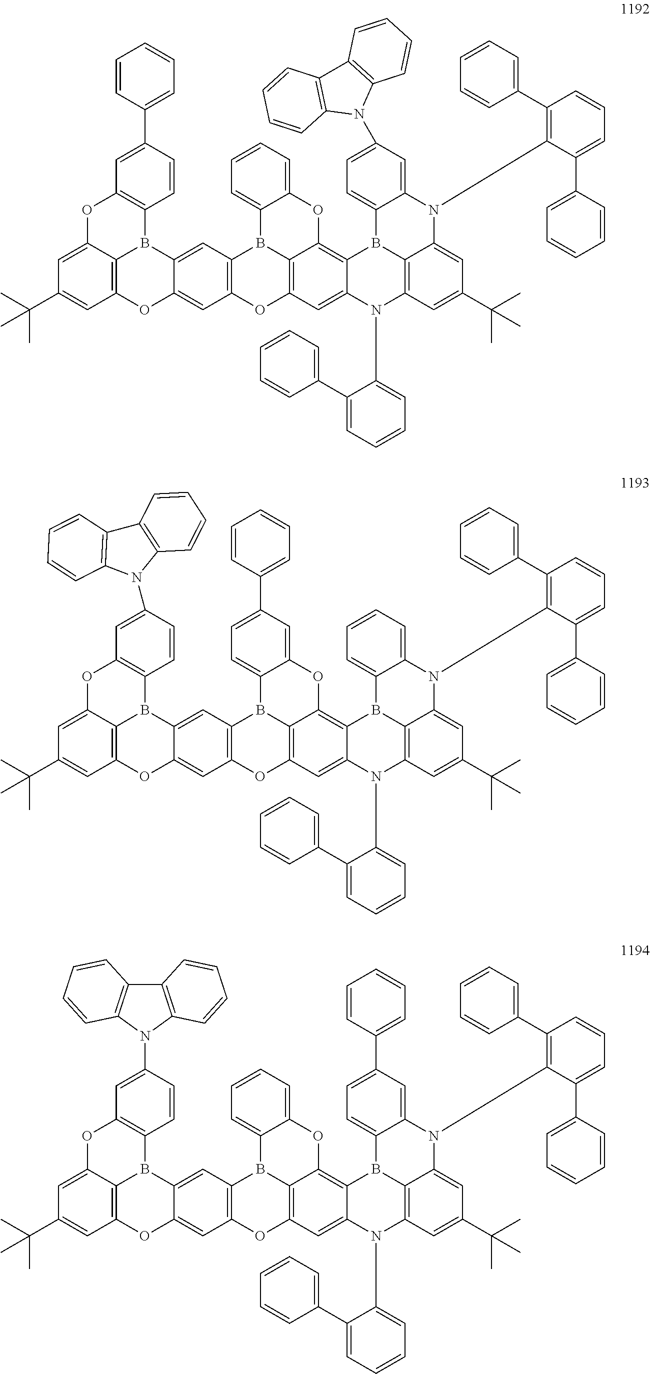

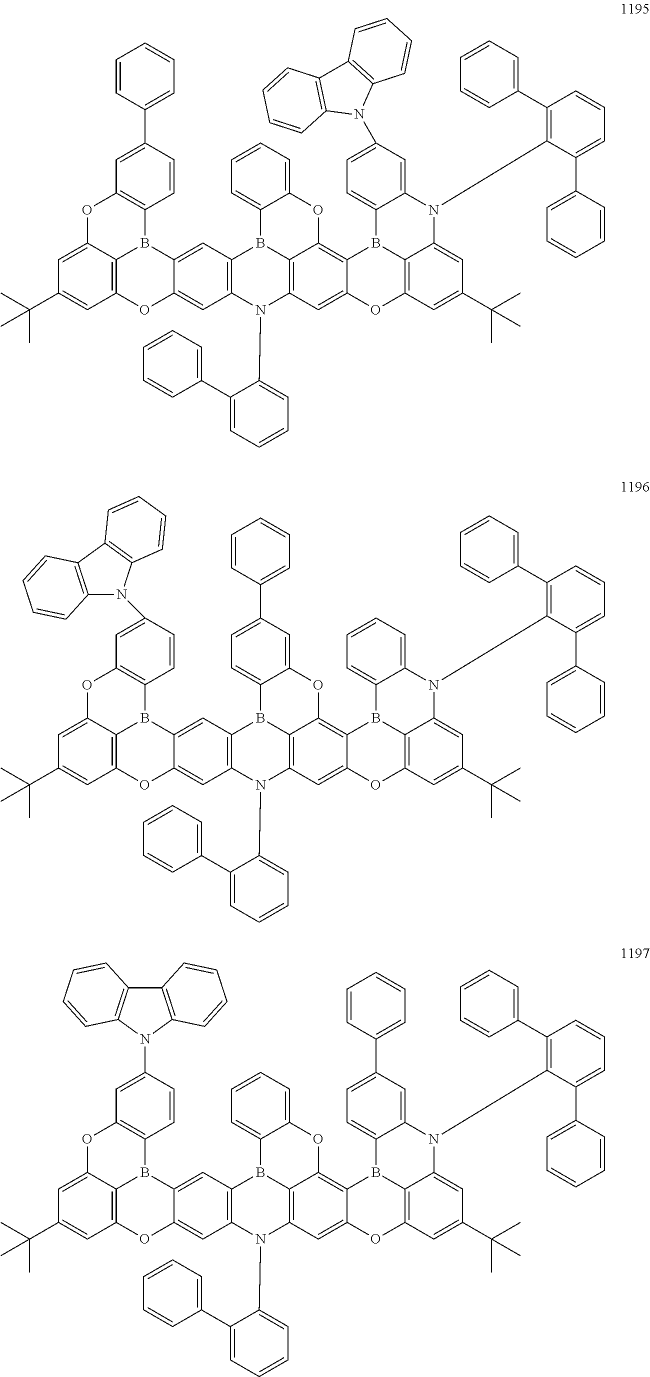

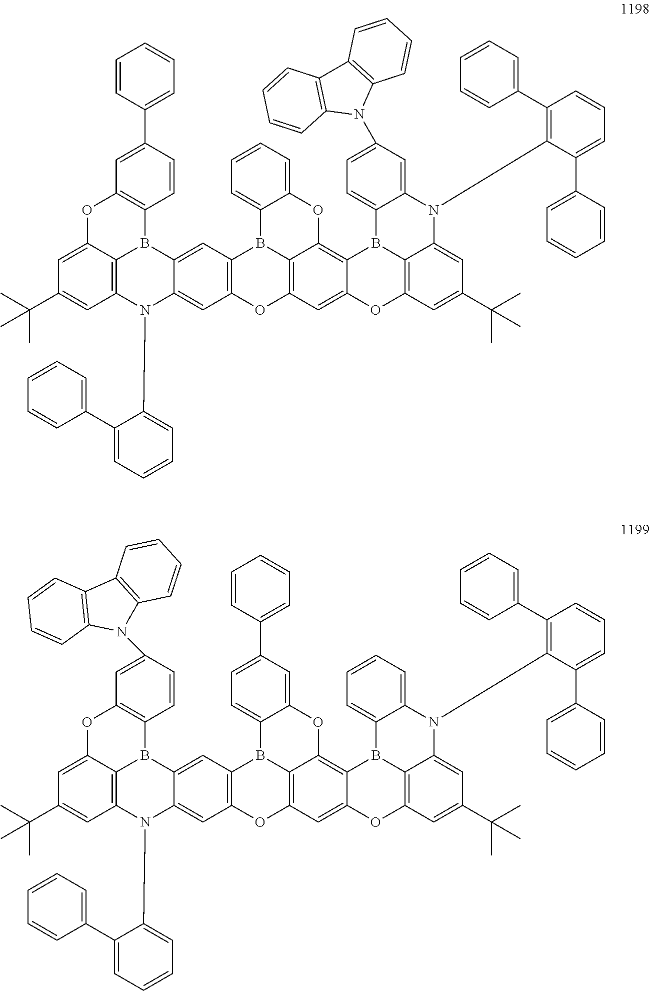 [SMILES: CC(C)(C)c1cc2c3c(c1)N(c1ccccc1-c1ccccc1)c1cc4c(cc1B3c1ccc(-c3ccccc3)cc1O2)B1c2ccccc2Oc2c1c(cc1c2B2c3ccc(-n5c6ccccc6c6ccccc65)cc3N(c3c(-c5ccccc5)cccc3-c3ccccc3)c3cc(C(C)(C)C)cc(c32)O1)O4 ; CC(C)(C)c1cc2c3c(c1)N(c1ccccc1-c1ccccc1)c1cc4c(cc1B3c1ccc(-n3c5ccccc5c5ccccc53)cc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)O1)O4]

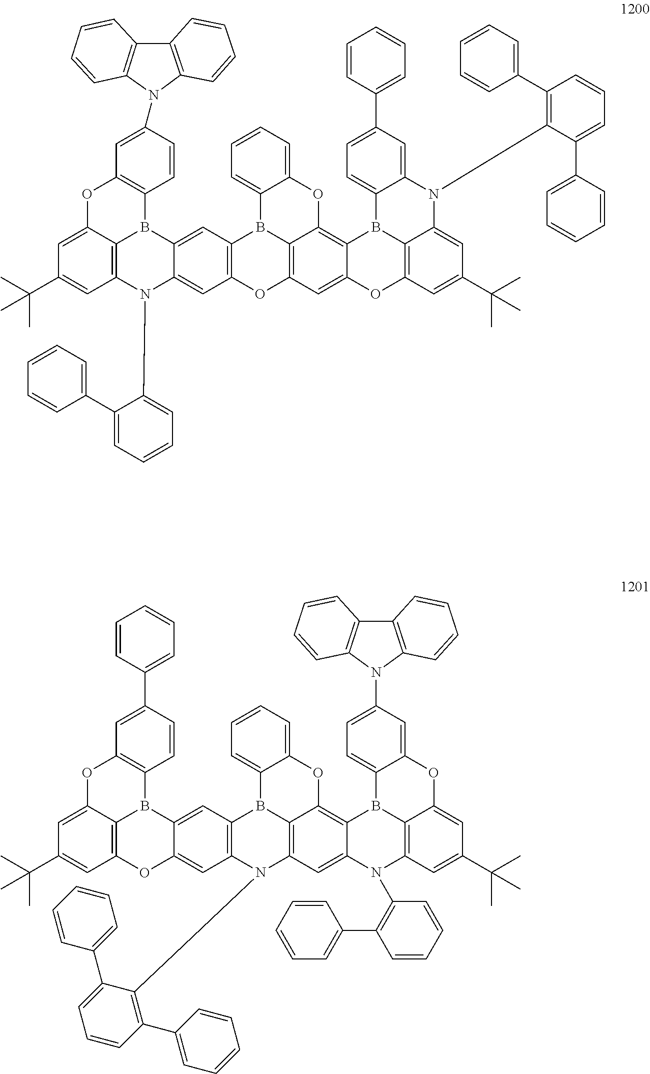 [SMILES: CC(C)(C)c1cc2c3c(c1)N(c1ccccc1-c1ccccc1)c1cc4c(cc1B3c1ccc(-n3c5ccccc5c5ccccc53)cc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)O1)O4 ; CC(C)(C)c1cc2c3c(c1)Oc1cc4c(cc1B3c1ccc(-c3ccccc3)cc1O2)B1c2ccccc2Oc2c3c(cc(c21)N4c1c(-c2ccccc2)cccc1-c1ccccc1)N(c1ccccc1-c1ccccc1)c1cc(C(C)(C)C)cc2c1B3c1ccc(-n3c4ccccc4c4ccccc43)cc1O2]

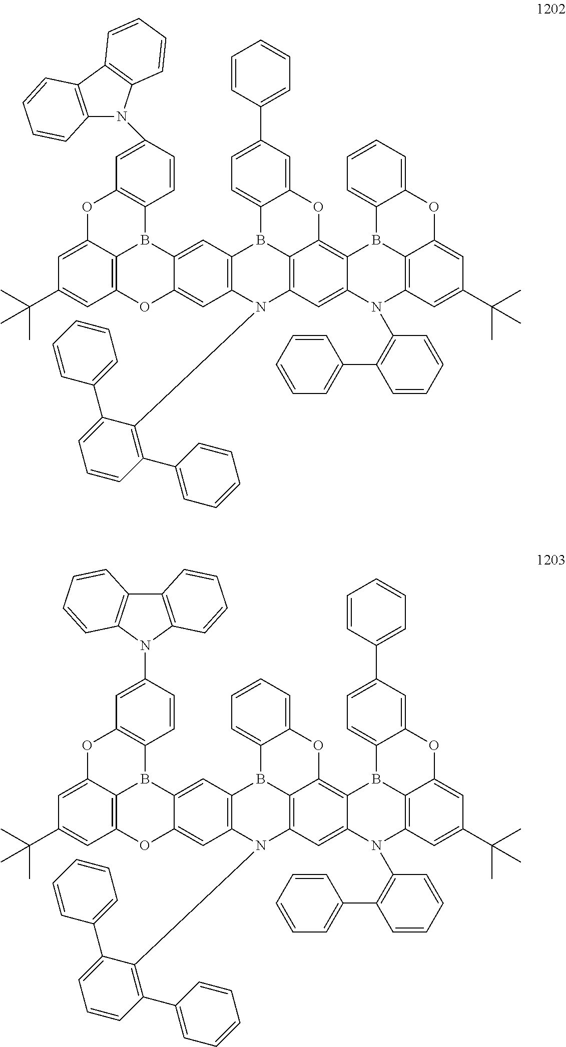

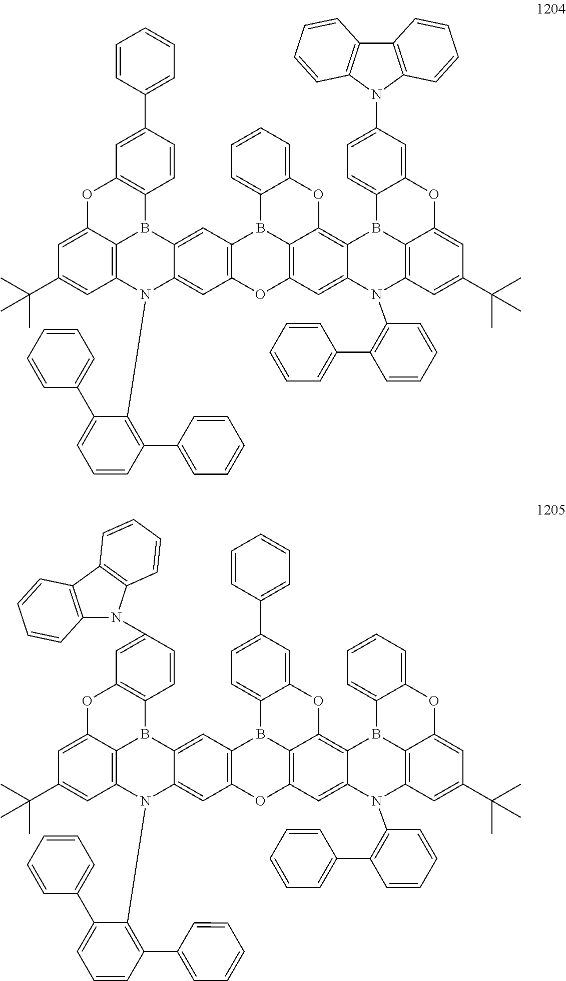

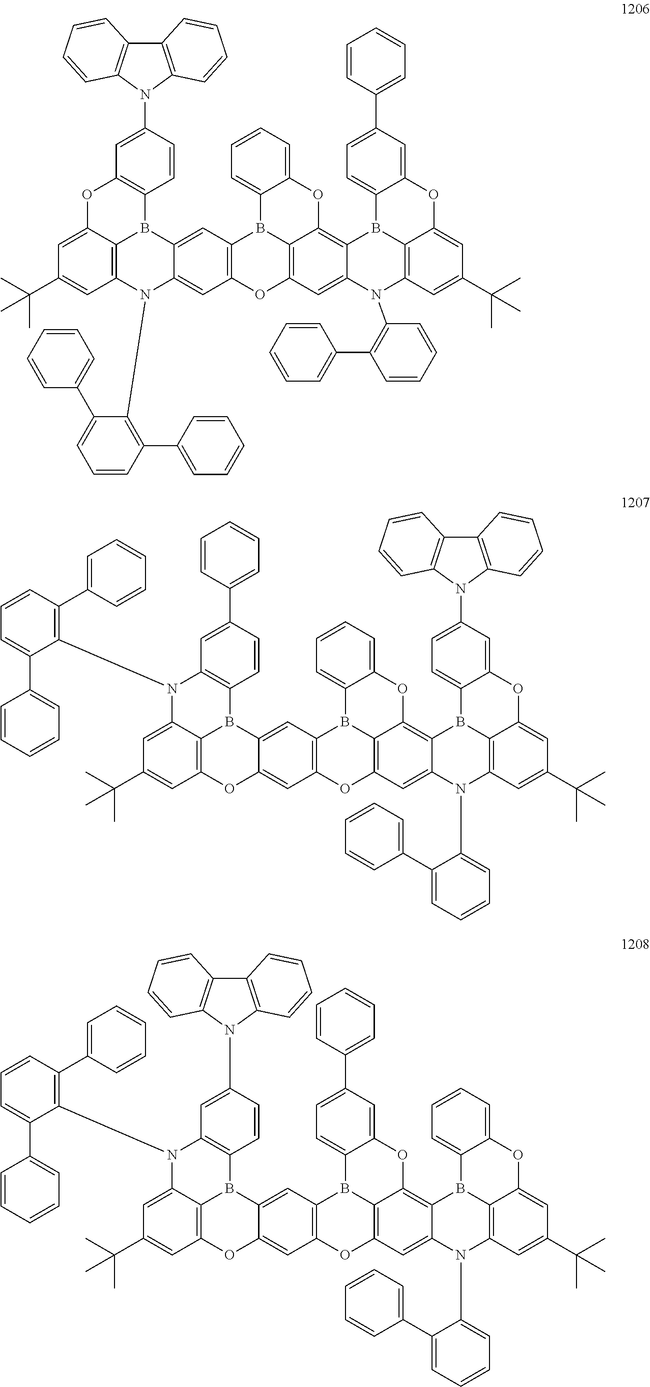

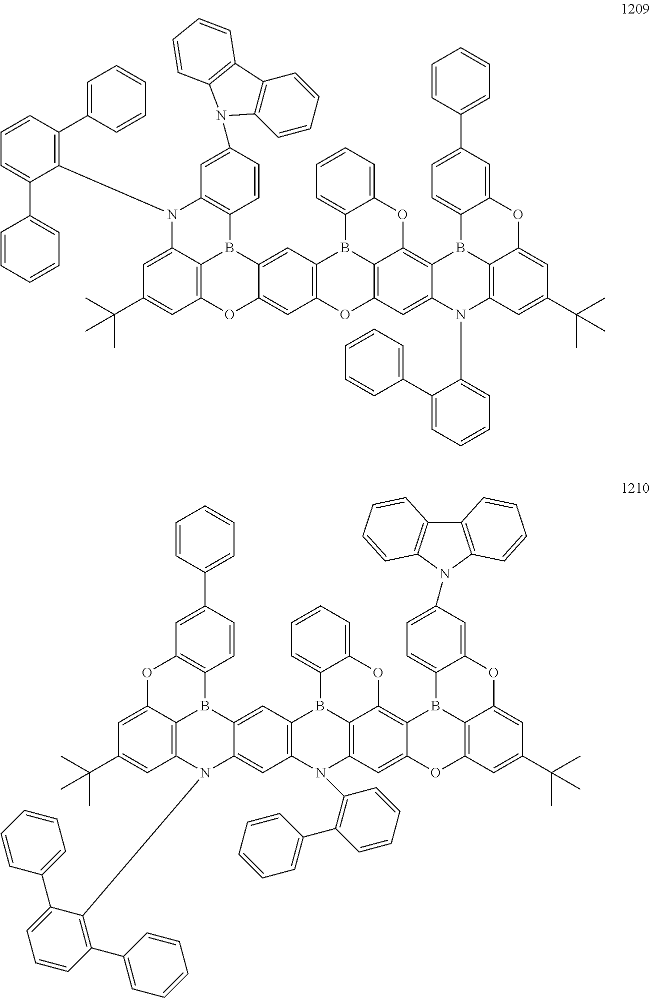 [SMILES: CC(C)(C)c1cc2c3c(c1)N(c1ccccc1-c1ccccc1)c1cc4c5c(c1B3c1ccc(-c3ccccc3)cc1O2)Oc1ccccc1B5c1cc2c(cc1O4)Oc1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-c2ccccc2)cc1O3]

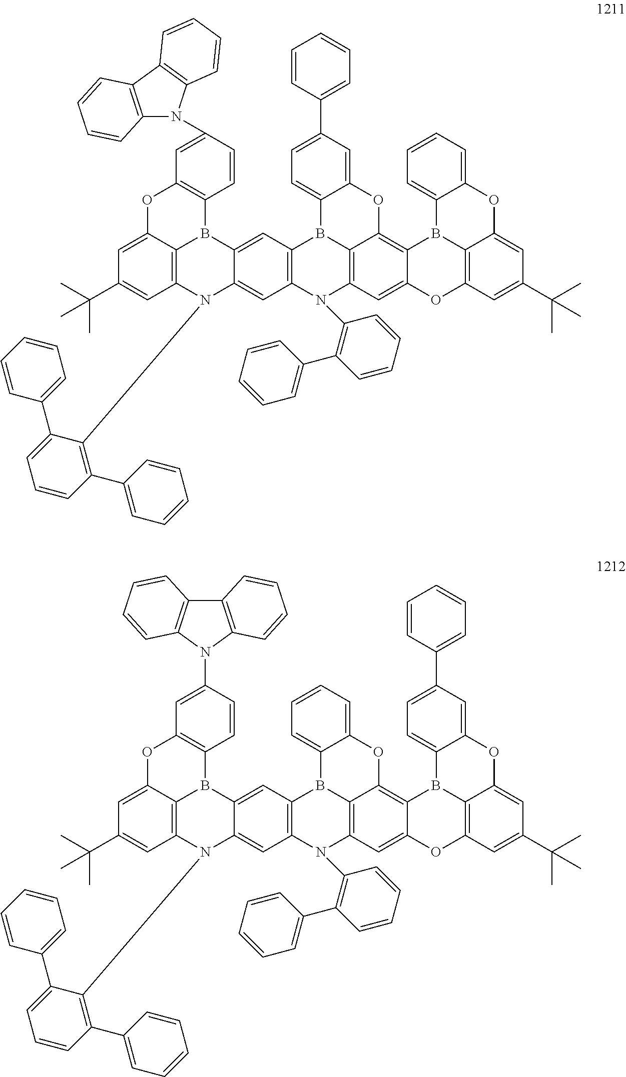 [SMILES: CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)N(c1c(-c3ccccc3)cccc1-c1ccccc1)c1cc(C(C)(C)C)cc3c1B2c1ccc(-n2c4ccccc4c4ccccc42)cc1O3 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-n2c4ccccc4c4ccccc42)cc1O3]

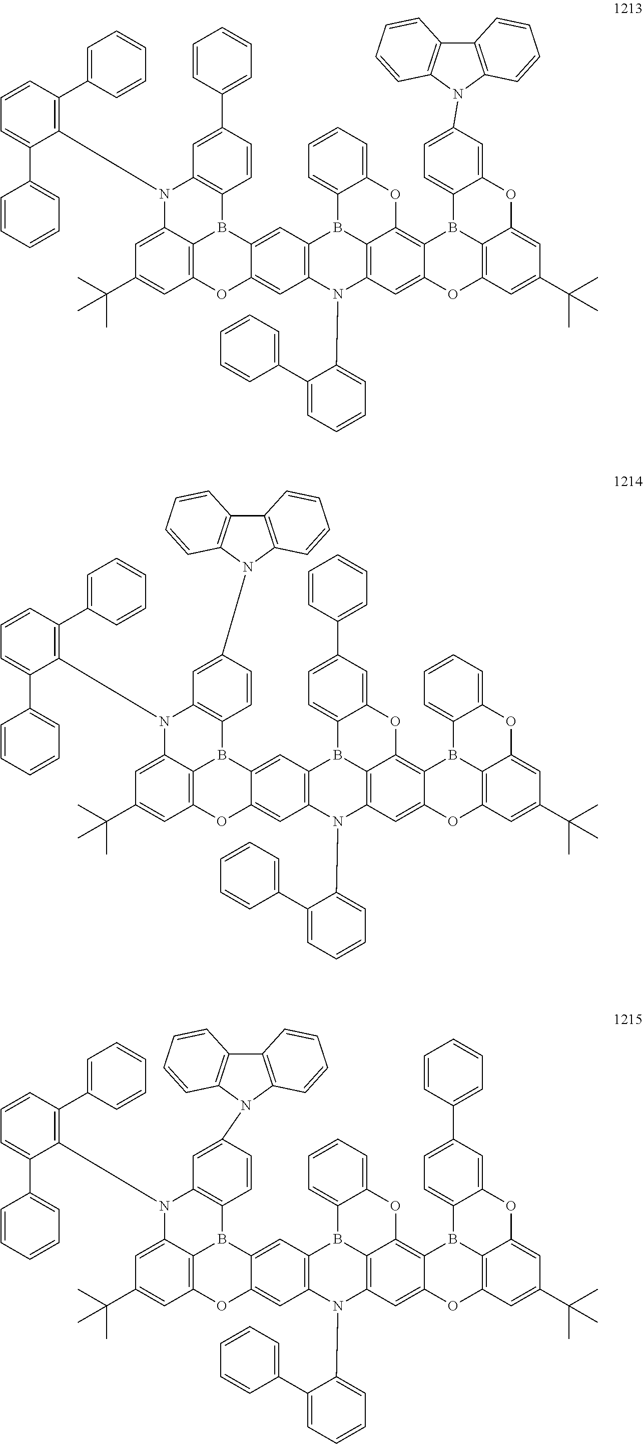

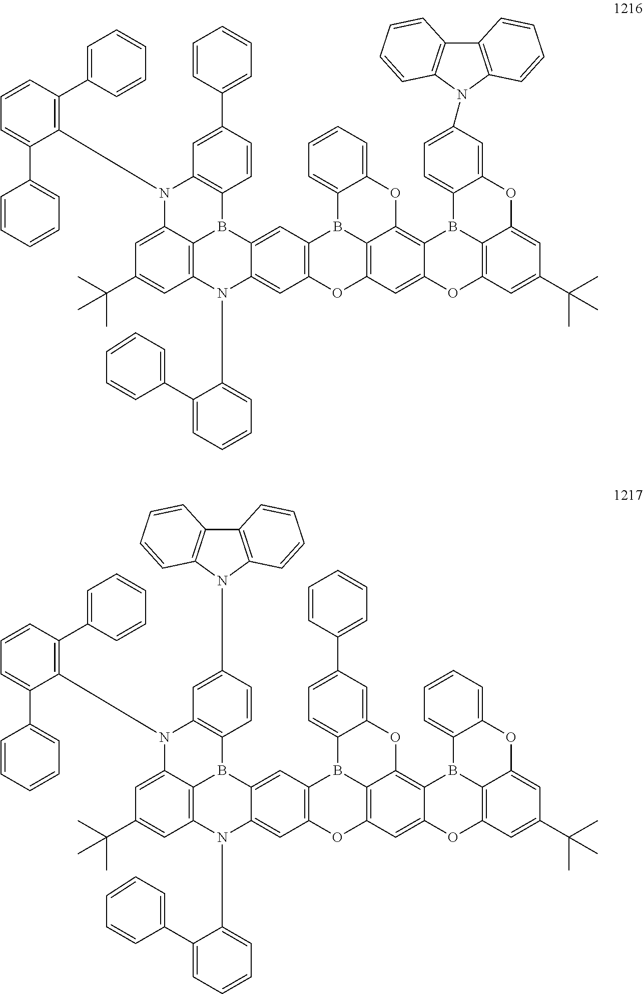 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1O4)N(c1ccccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1O4)N(c1ccccc1-c1ccccc1)c1cc(C(C)(C)C)cc3c1B2c1ccc(-n2c4ccccc4c4ccccc42)cc1N3c1c(-c2ccccc2)cccc1-c1ccccc1]

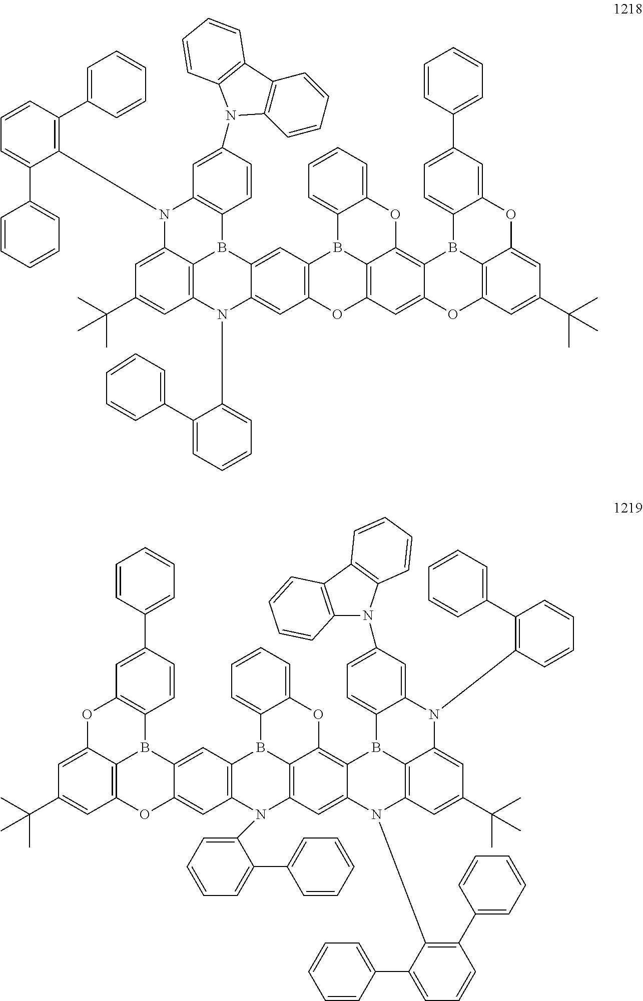

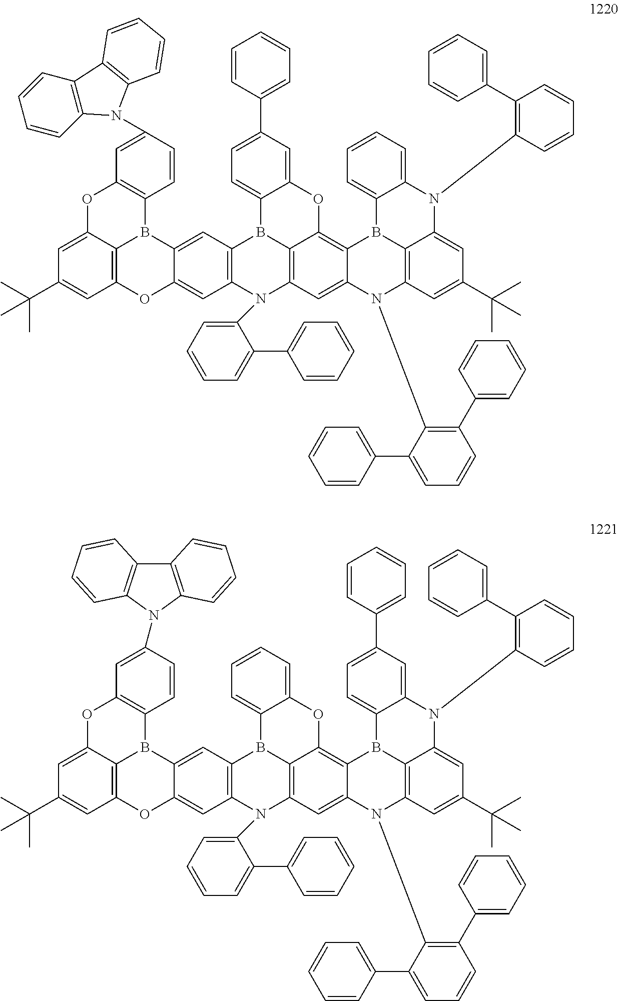 [SMILES: CC(C)(C)c1cc2c3c(c1)Oc1cc4c(cc1B3c1ccc(-n3c5ccccc5c5ccccc53)cc1O2)B1c2ccc(-c3ccccc3)cc2Oc2c1c(cc1c2B2c3ccccc3N(c3ccccc3-c3ccccc3)c3cc(C(C)(C)C)cc(c32)N1c1c(-c2ccccc2)cccc1-c1ccccc1)N4c1ccccc1-c1ccccc1 ; CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccc(-c5ccccc5)cc3N(c3ccccc3-c3ccccc3)c3cc(C(C)(C)C)cc(c32)N1c1c(-c2ccccc2)cccc1-c1ccccc1)N4c1ccccc1-c1ccccc1]

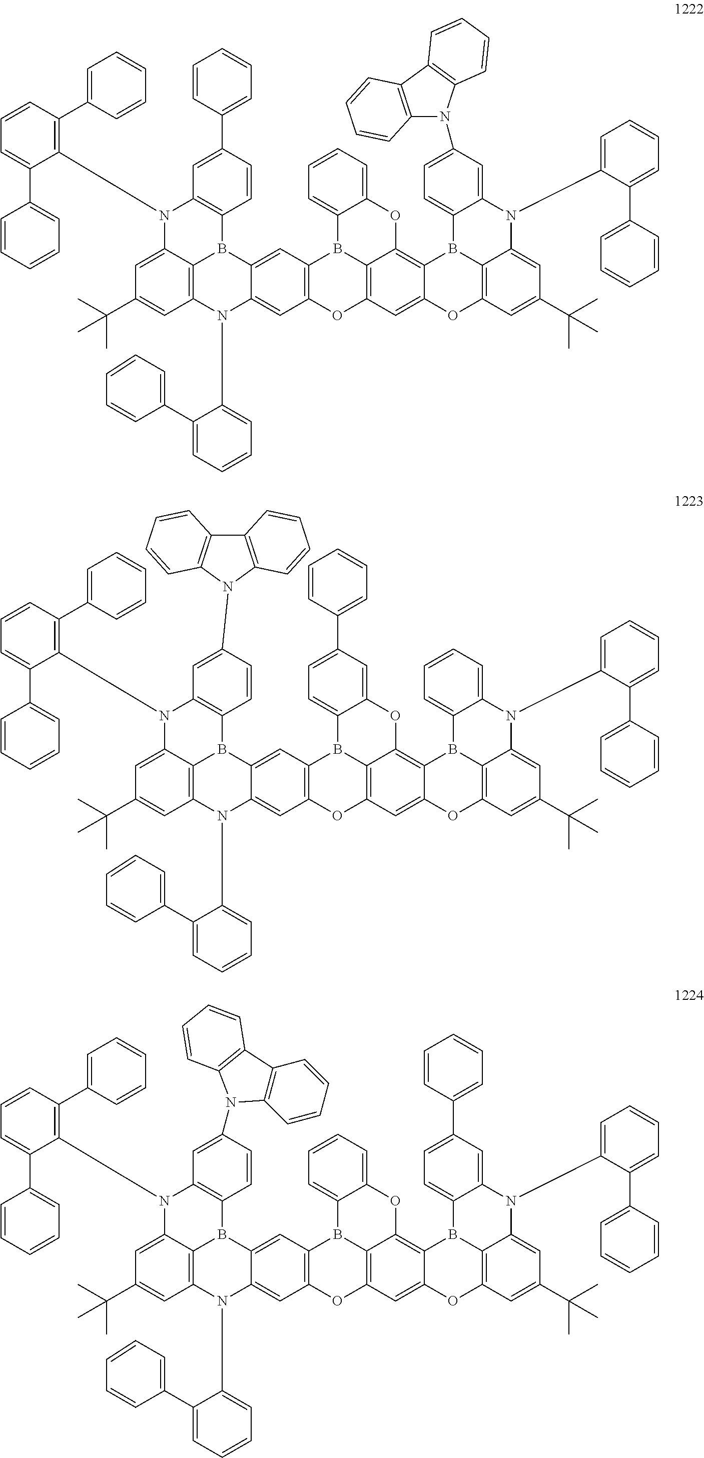

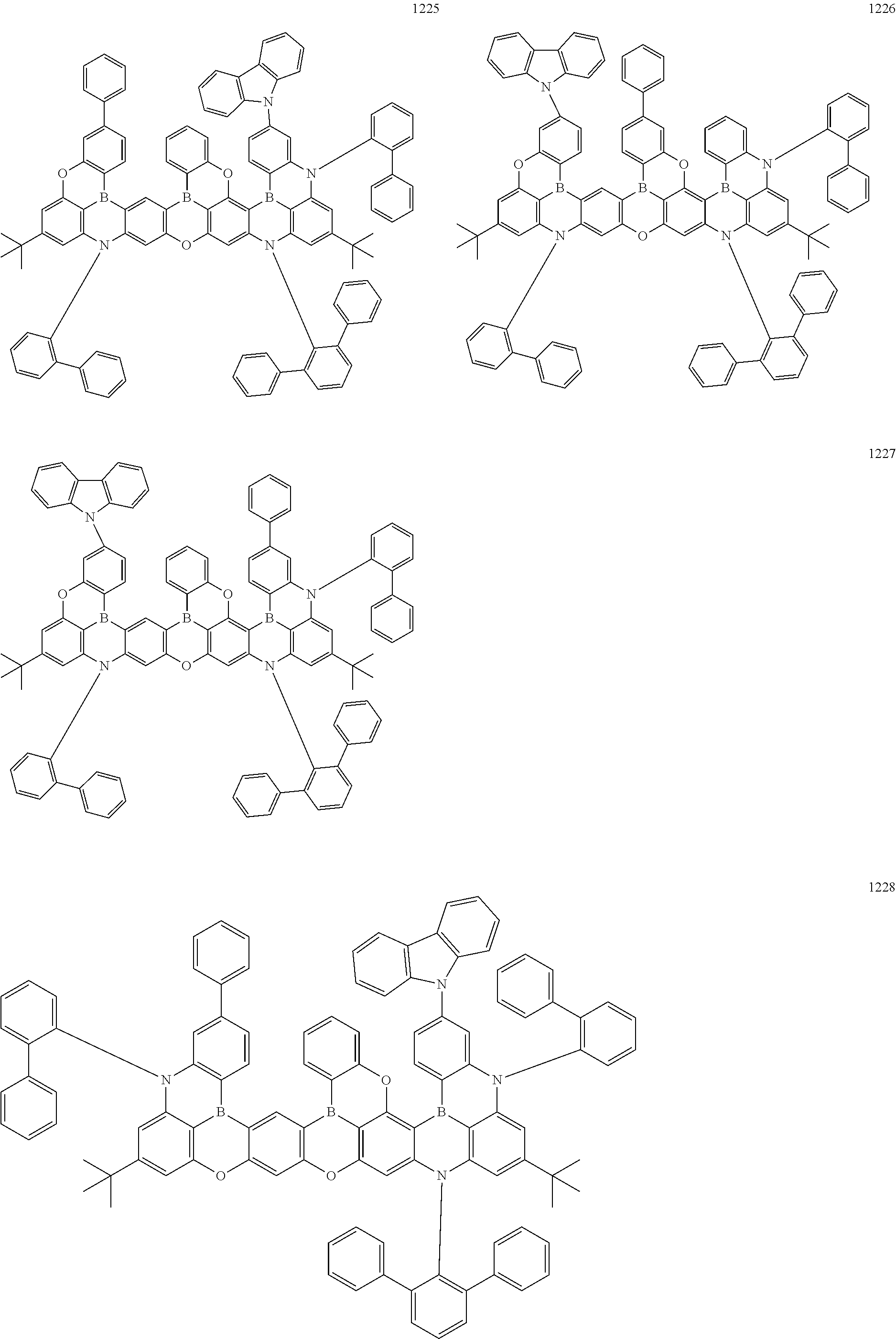

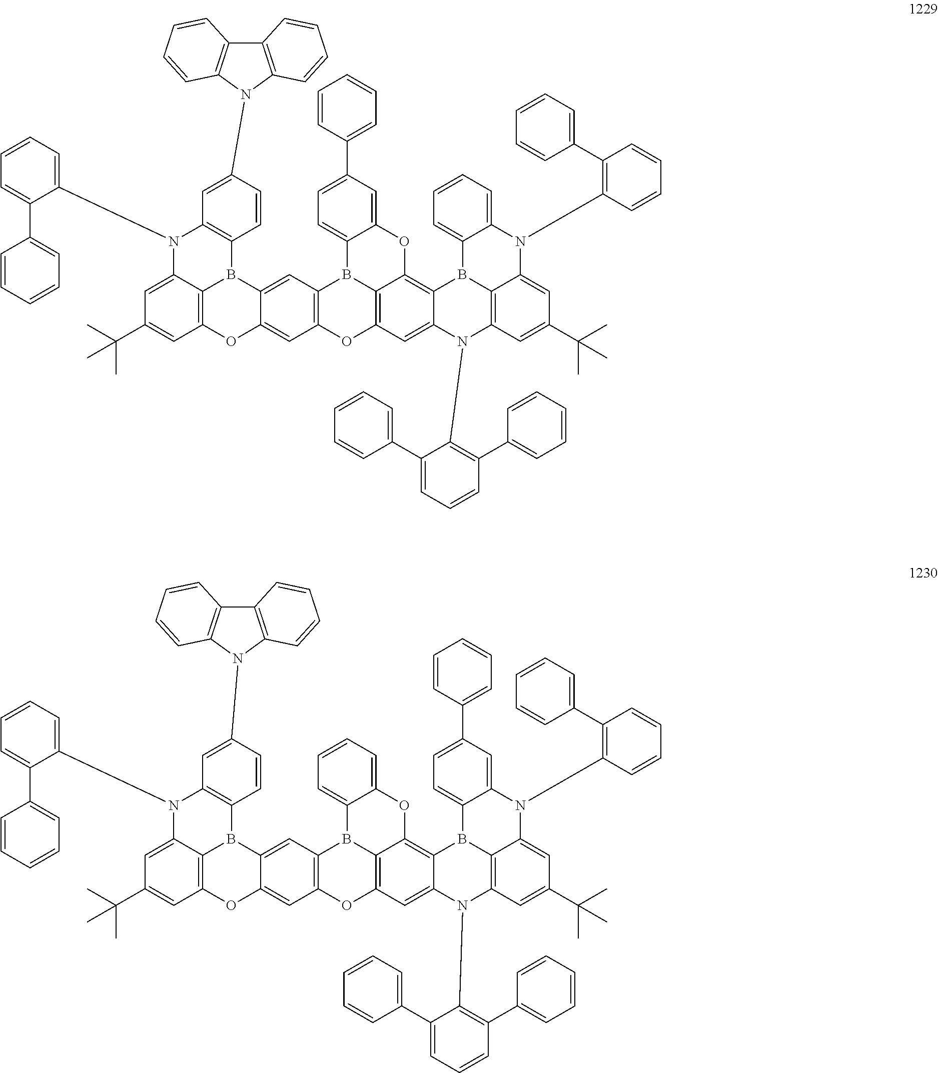 [SMILES: CC(C)(C)c1cc2c3c(c1)N(c1ccccc1-c1ccccc1)c1cc(-n4c5ccccc5c5ccccc54)ccc1B3c1cc3c(cc1O2)Oc1cc2c(c4c1B3c1ccc(-c3ccccc3)cc1O4)B1c3ccccc3N(c3ccccc3-c3ccccc3)c3cc(C(C)(C)C)cc(c31)N2c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1cc3c(cc1O2)Oc1cc2c(c4c1B3c1ccccc1O4)B1c3ccc(-c4ccccc4)cc3N(c3ccccc3-c3ccccc3)c3cc(C(C)(C)C)cc(c31)N2c1c(-c2ccccc2)cccc1-c1ccccc1]

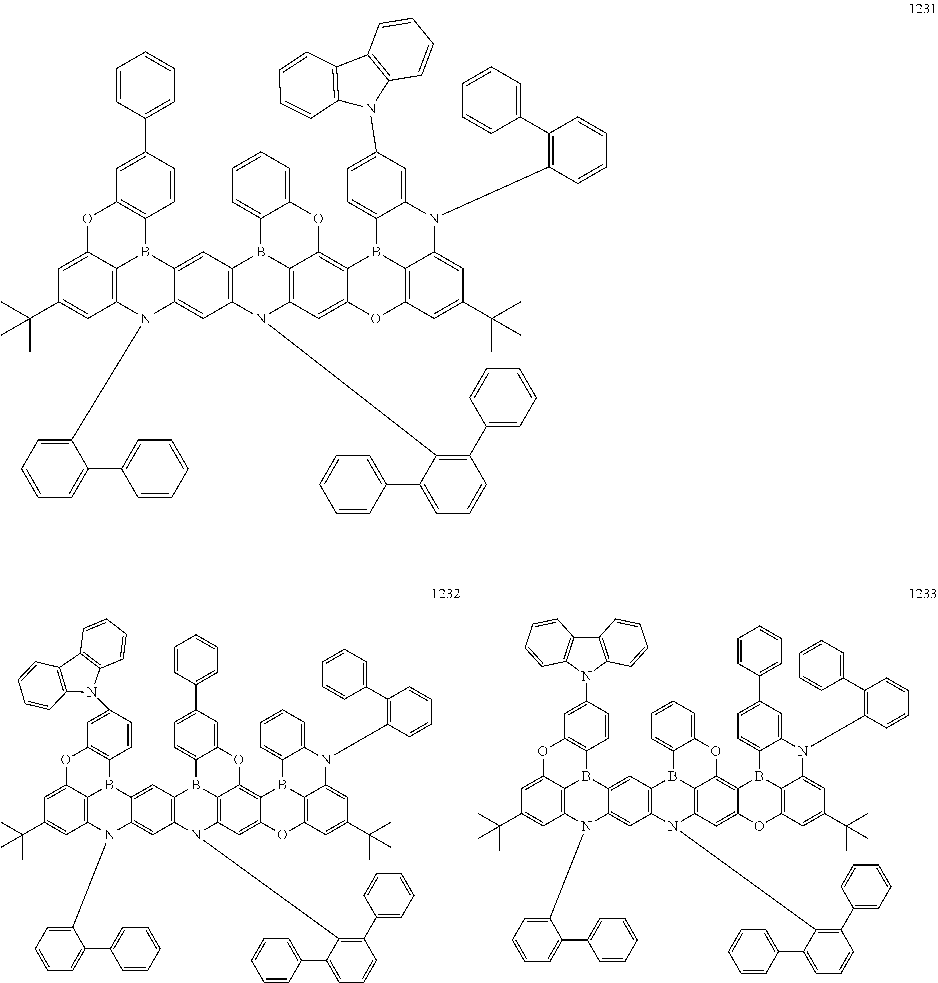

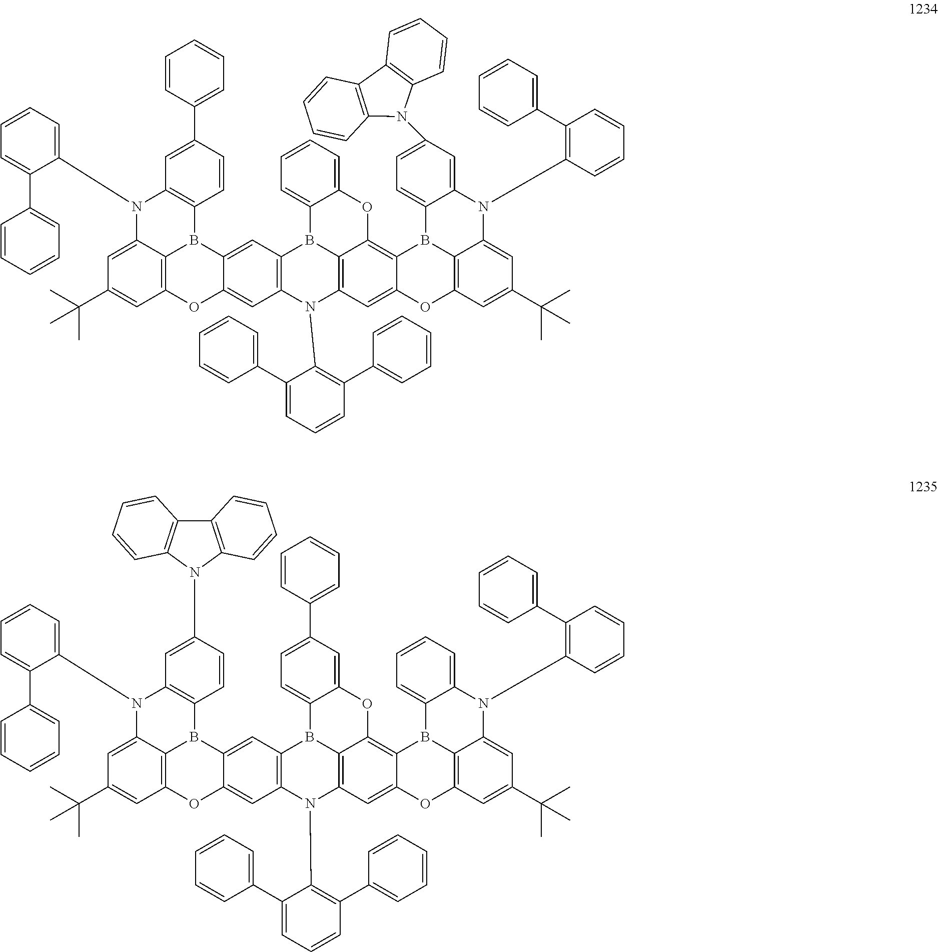 [SMILES: CC(C)(C)c1cc2c3c(c1)N(c1ccccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3N(c3ccccc3-c3ccccc3)c3cc(C(C)(C)C)cc(c31)O2 ; CC(C)(C)c1cc2c3c(c1)N(c1ccccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3N(c3ccccc3-c3ccccc3)c3cc(C(C)(C)C)cc(c31)O2]

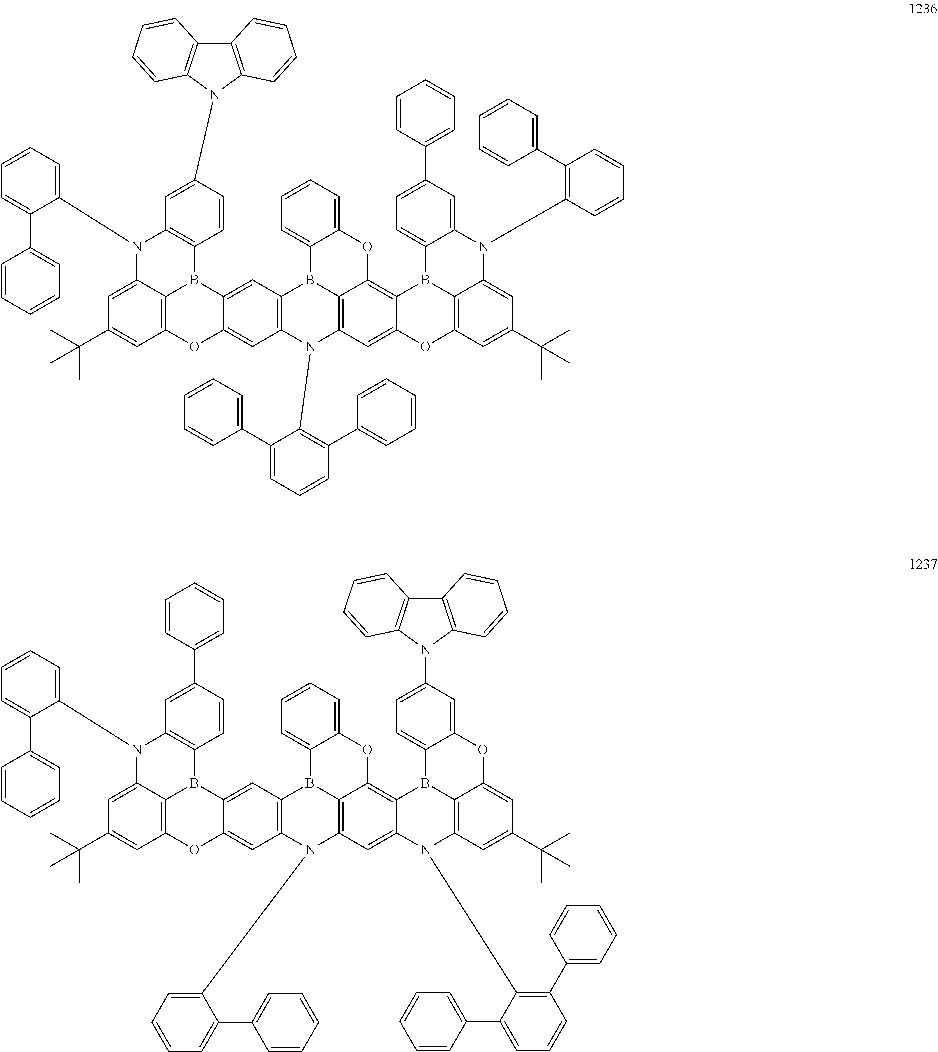 [SMILES: CC(C)(C)c1cc2c3c(c1)N(c1ccccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3N(c3ccccc3-c3ccccc3)c3cc(C(C)(C)C)cc(c31)O2 ; CC(C)(C)c1cc2c3c(c1)N(c1ccccc1-c1ccccc1)c1cc(-c4ccccc4)ccc1B3c1cc3c(cc1O2)N(c1ccccc1-c1ccccc1)c1cc2c(c4c1B3c1ccccc1O4)B1c3ccc(-n4c5ccccc5c5ccccc54)cc3Oc3cc(C(C)(C)C)cc(c31)N2c1c(-c2ccccc2)cccc1-c1ccccc1]

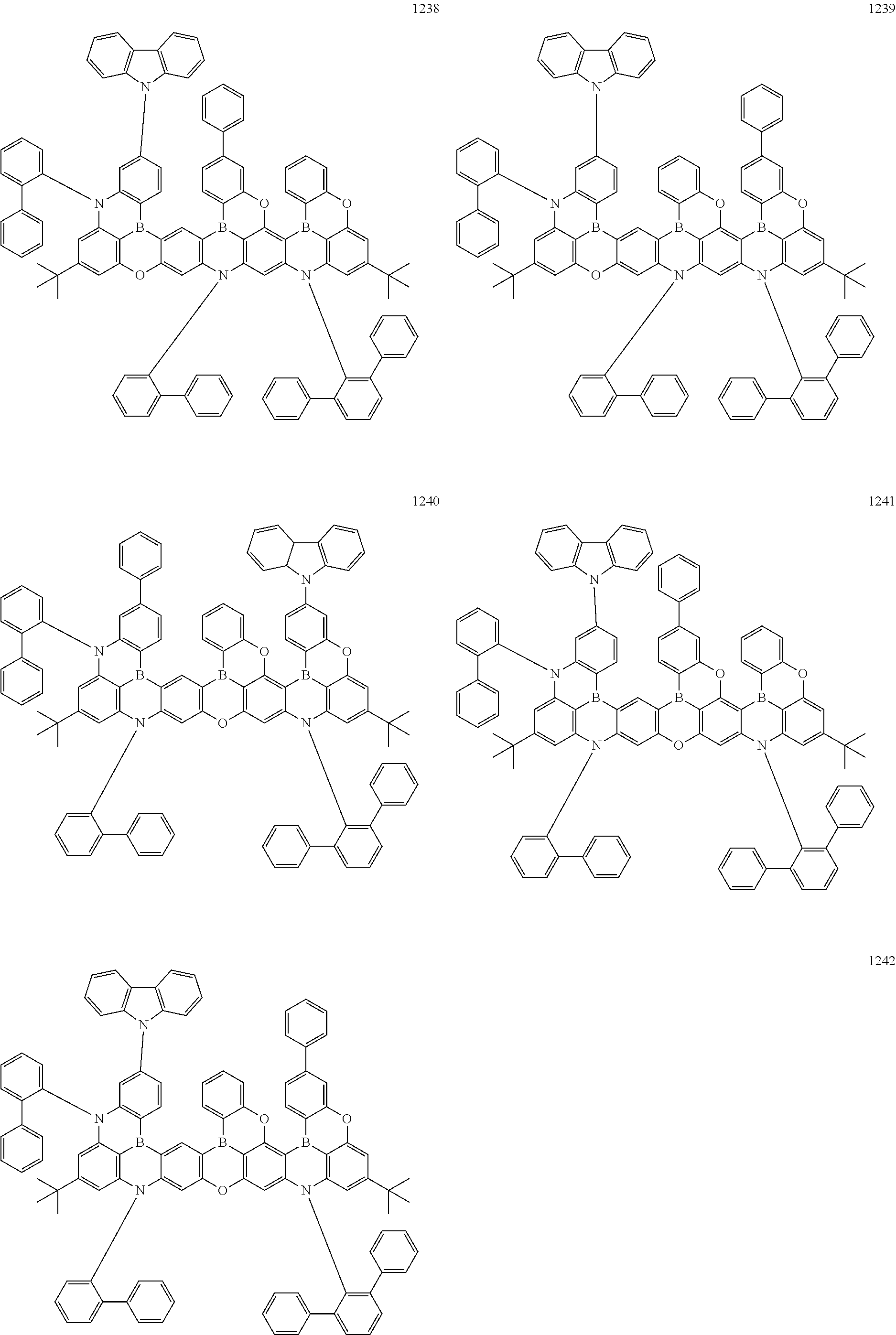

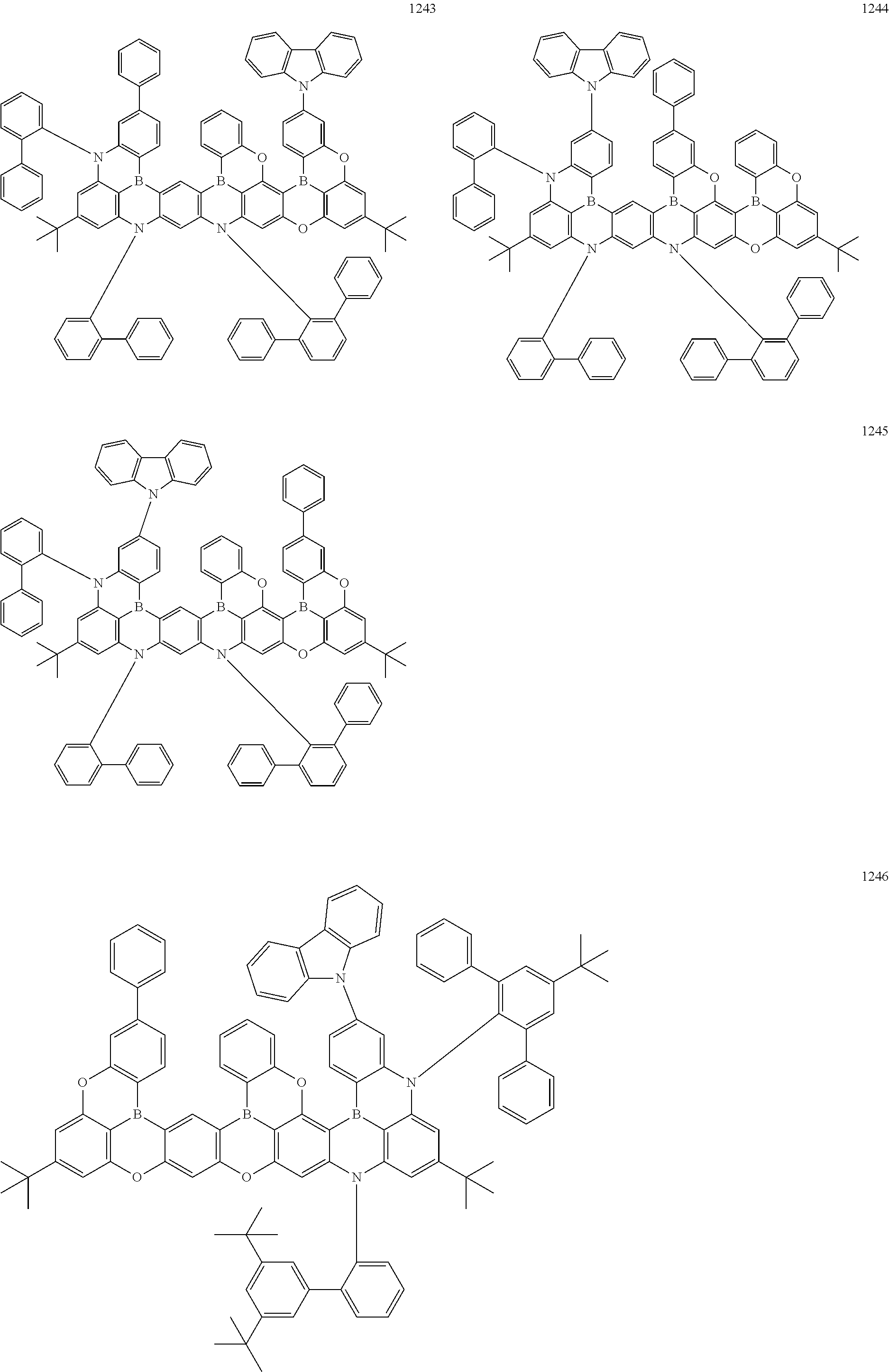

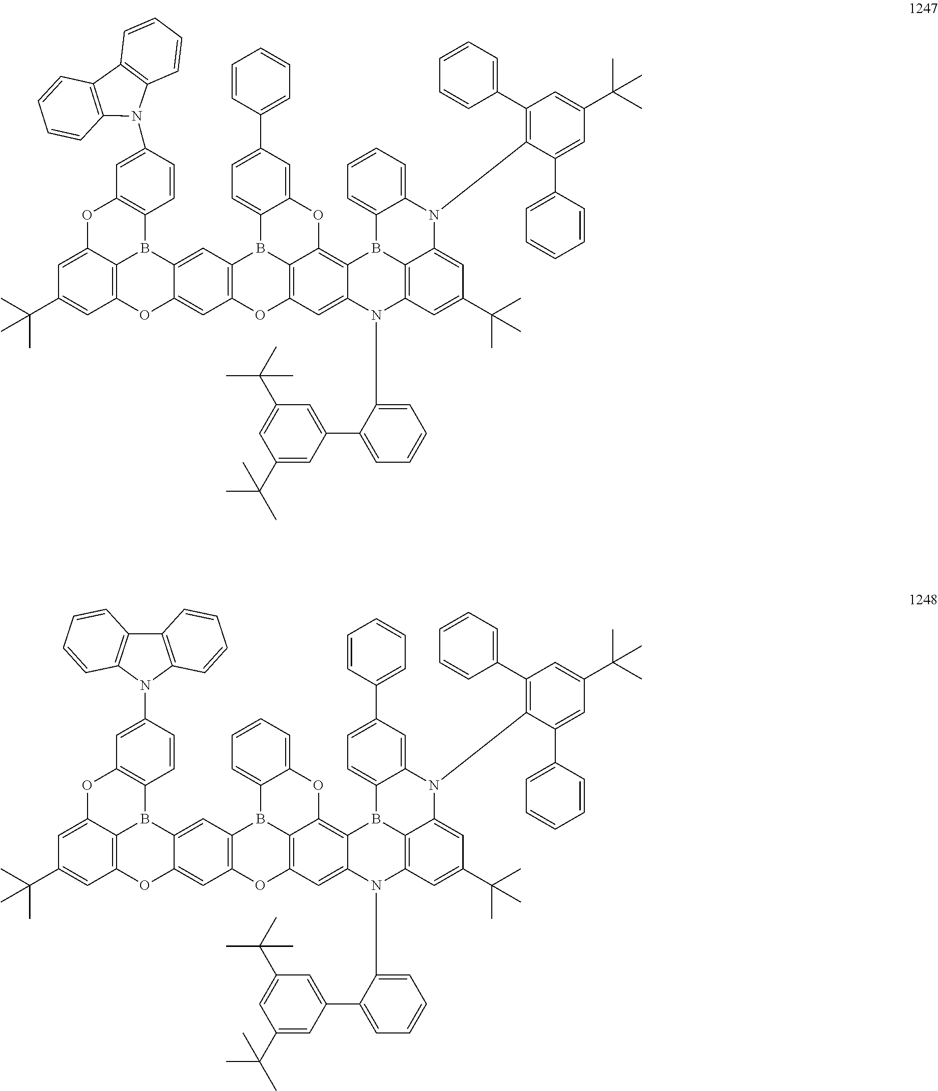

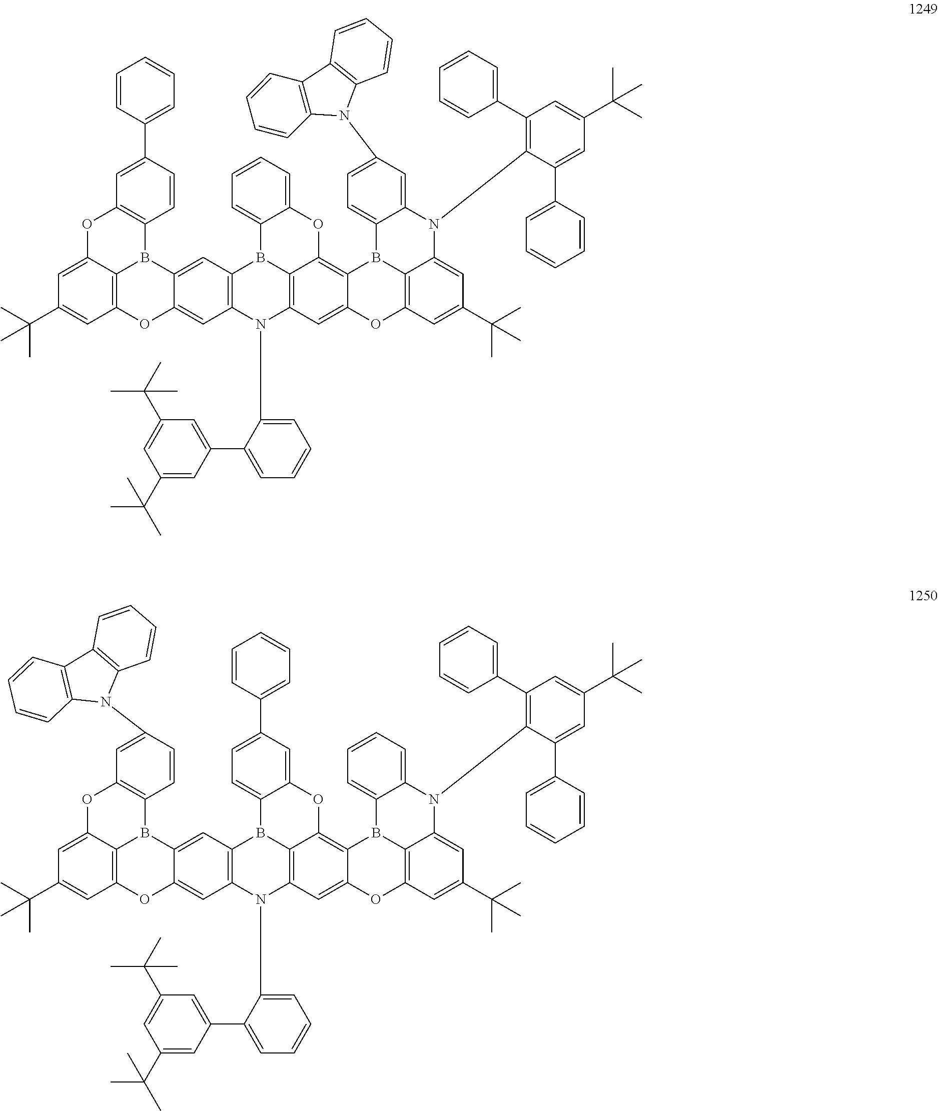

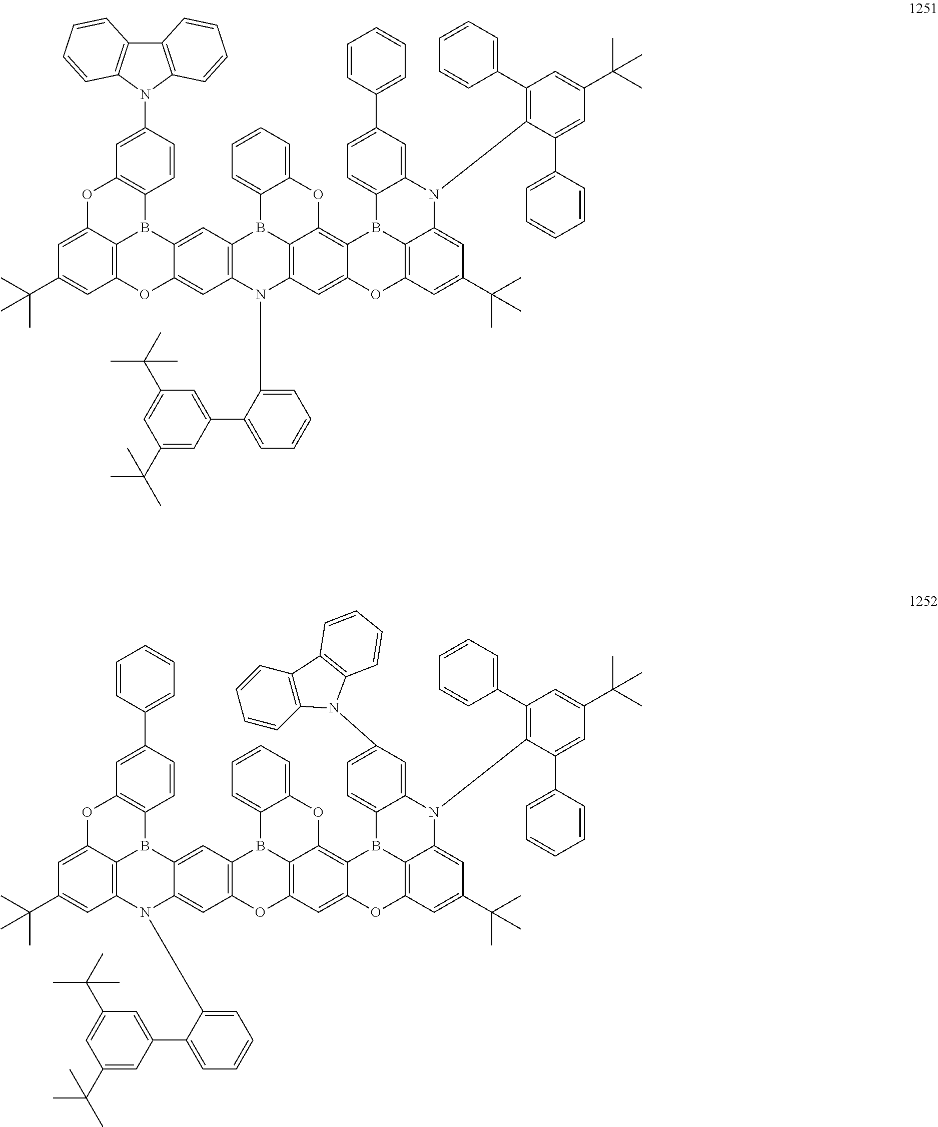

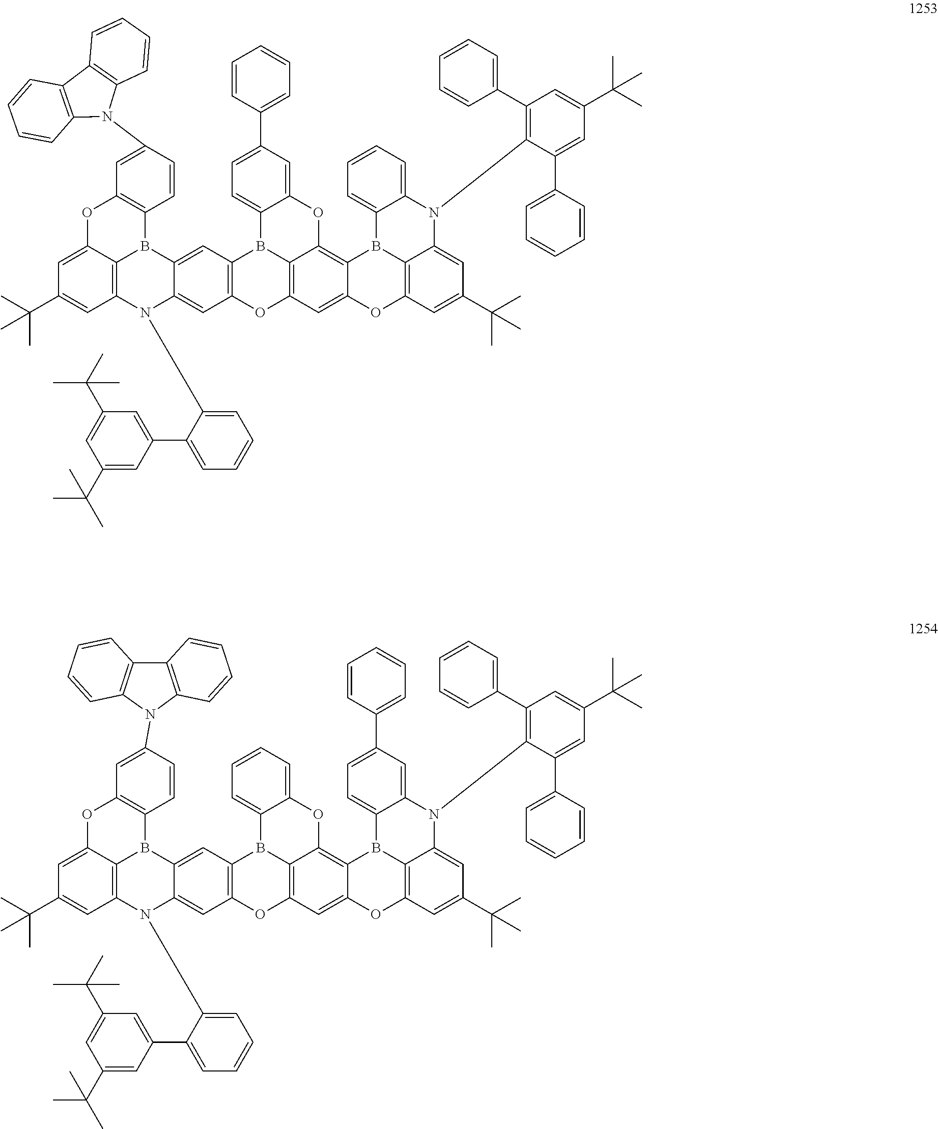

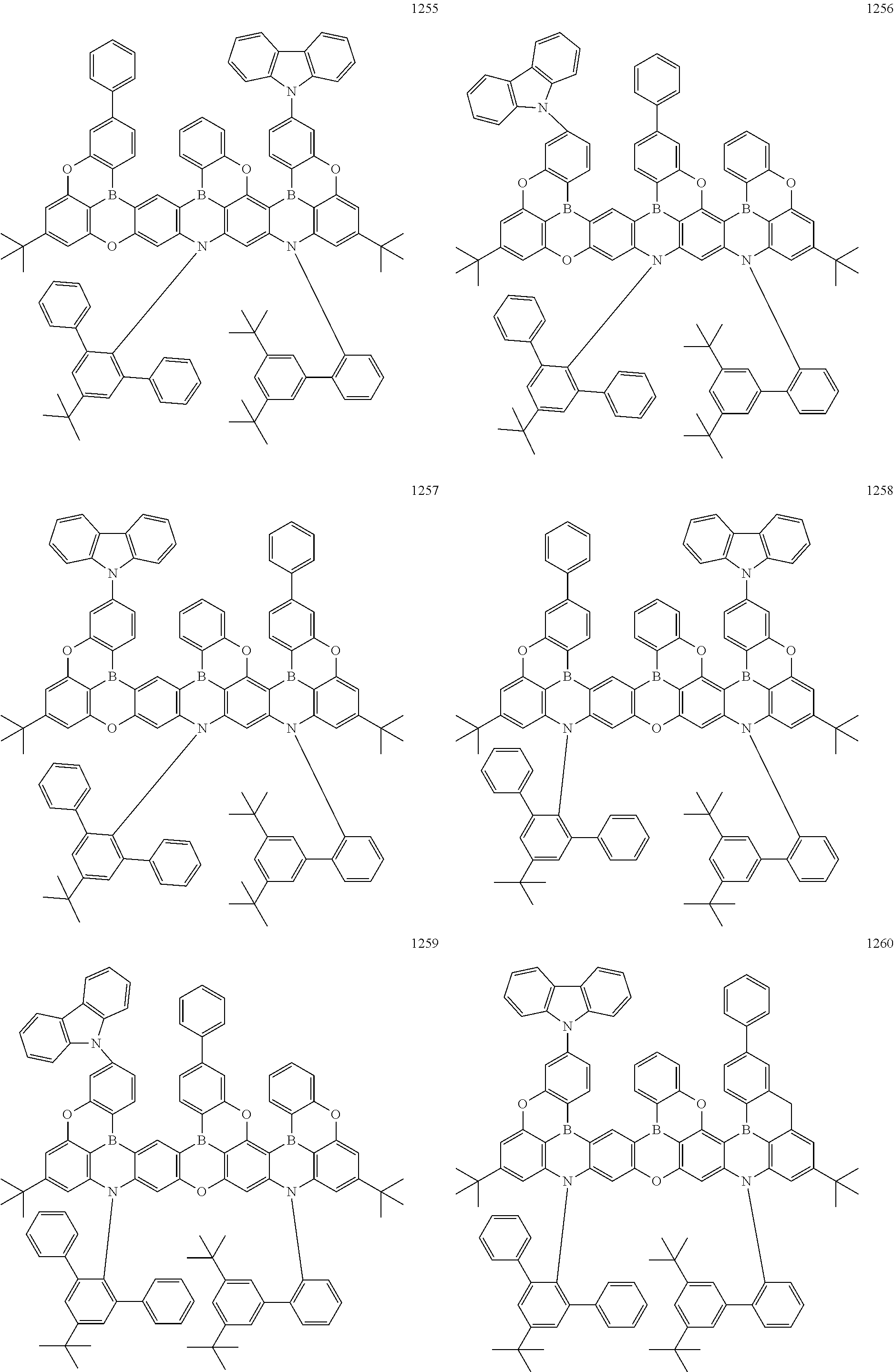

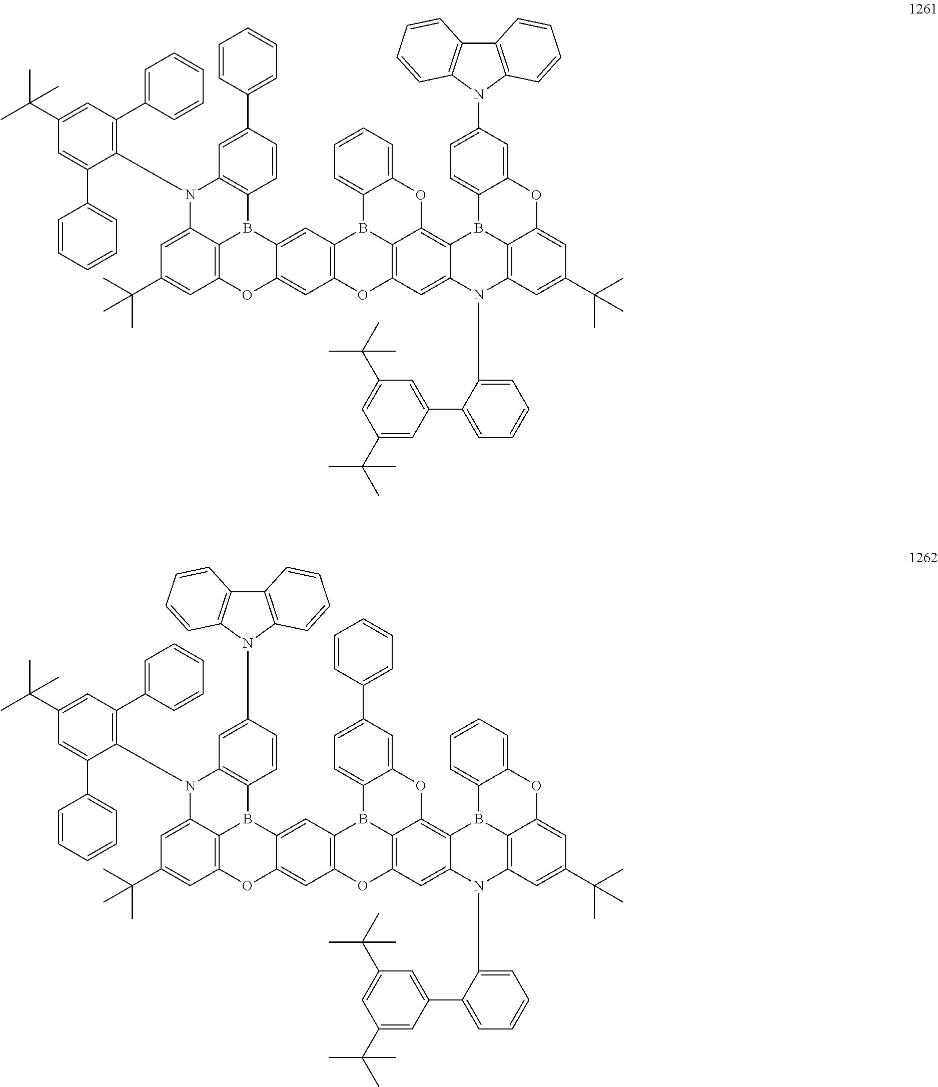

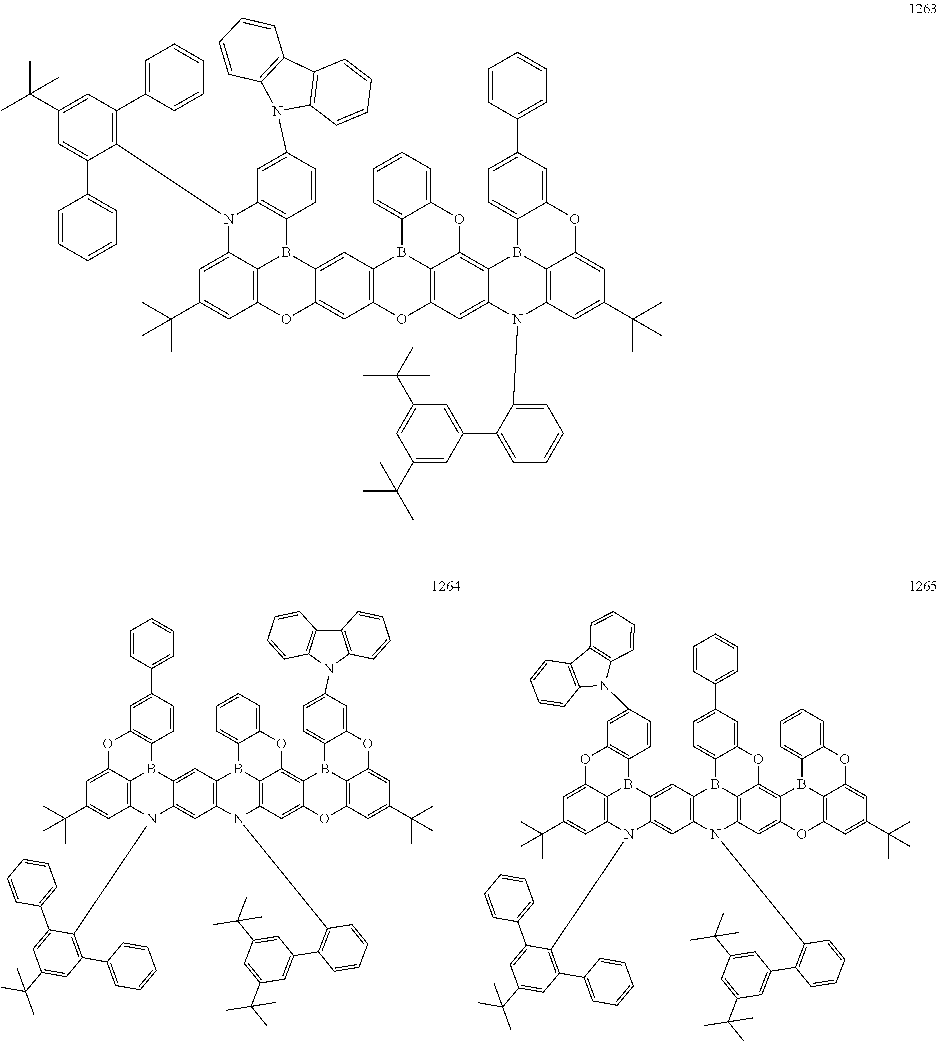

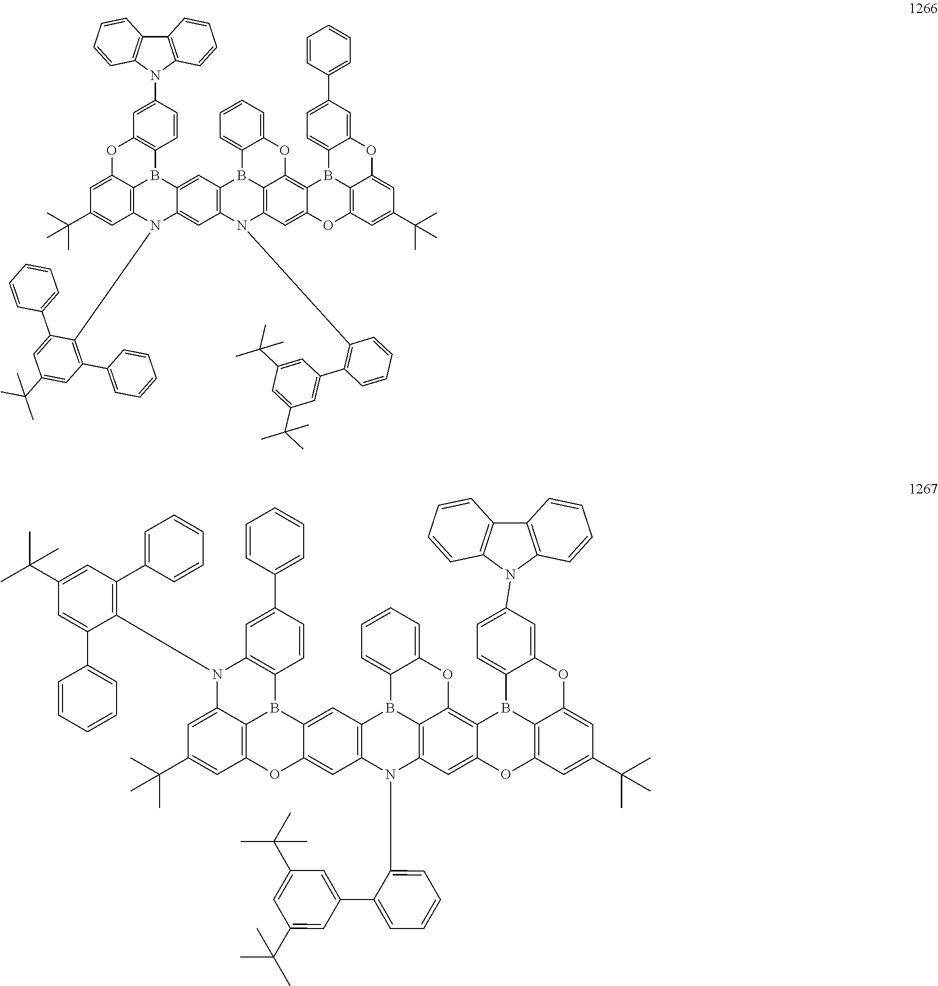

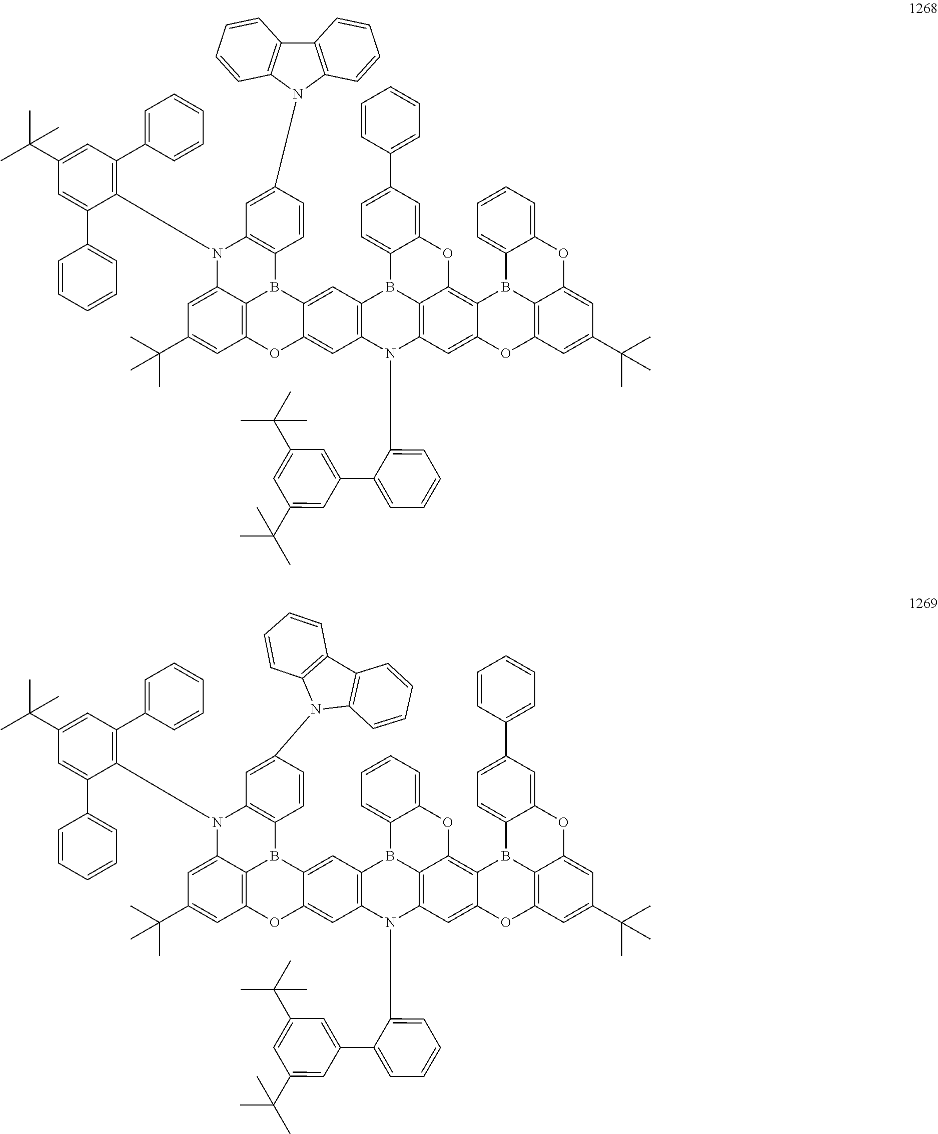

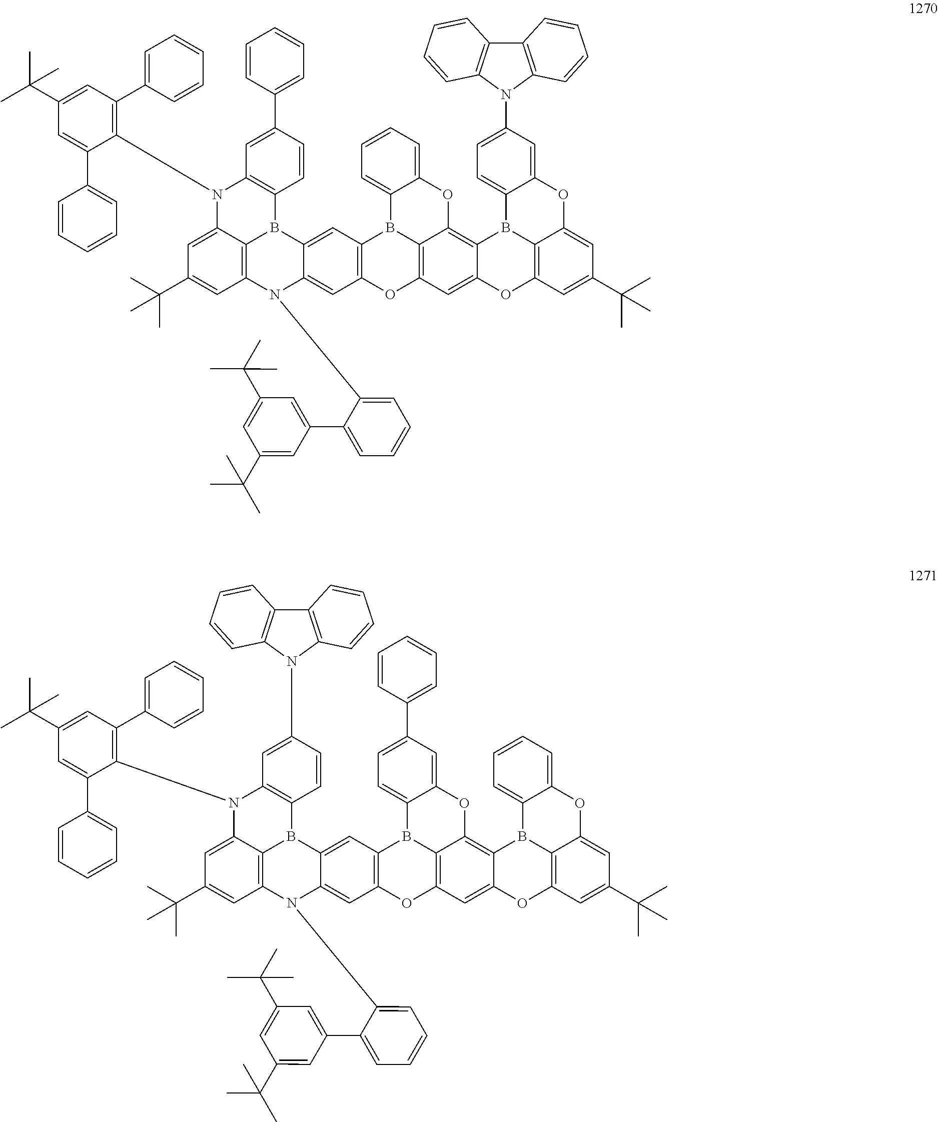

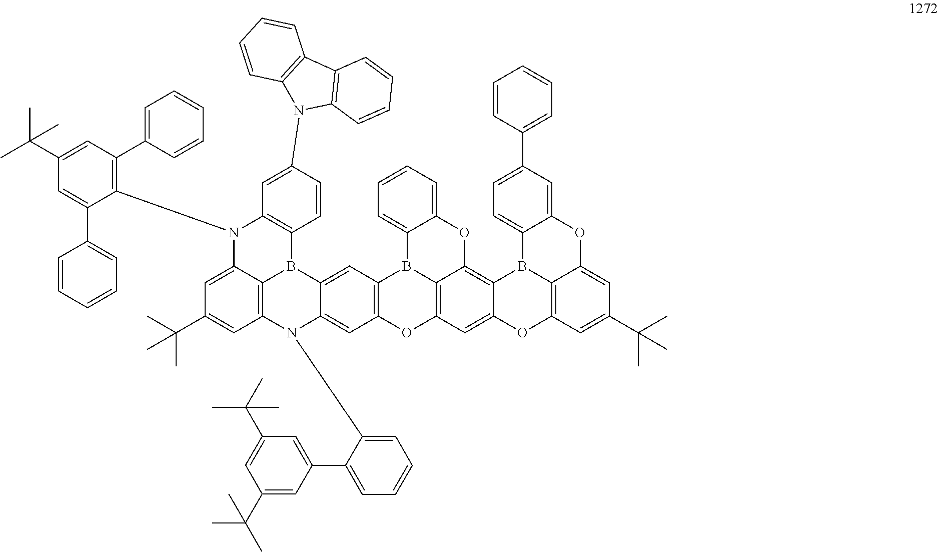 [SMILES: CC(C)(C)c1cc(-c2ccccc2N2c3cc4c(cc3B3c5ccc(-n6c7ccccc7c7ccccc76)cc5N(c5c(-c6ccccc6)cc(C(C)(C)C)cc5-c5ccccc5)c5cc(C(C)(C)C)cc2c53)B2c3ccccc3Oc3c2c(cc2c3B3c5ccc(-c6ccccc6)cc5Oc5cc(C(C)(C)C)cc(c53)O2)O4)cc(C(C)(C)C)c1]

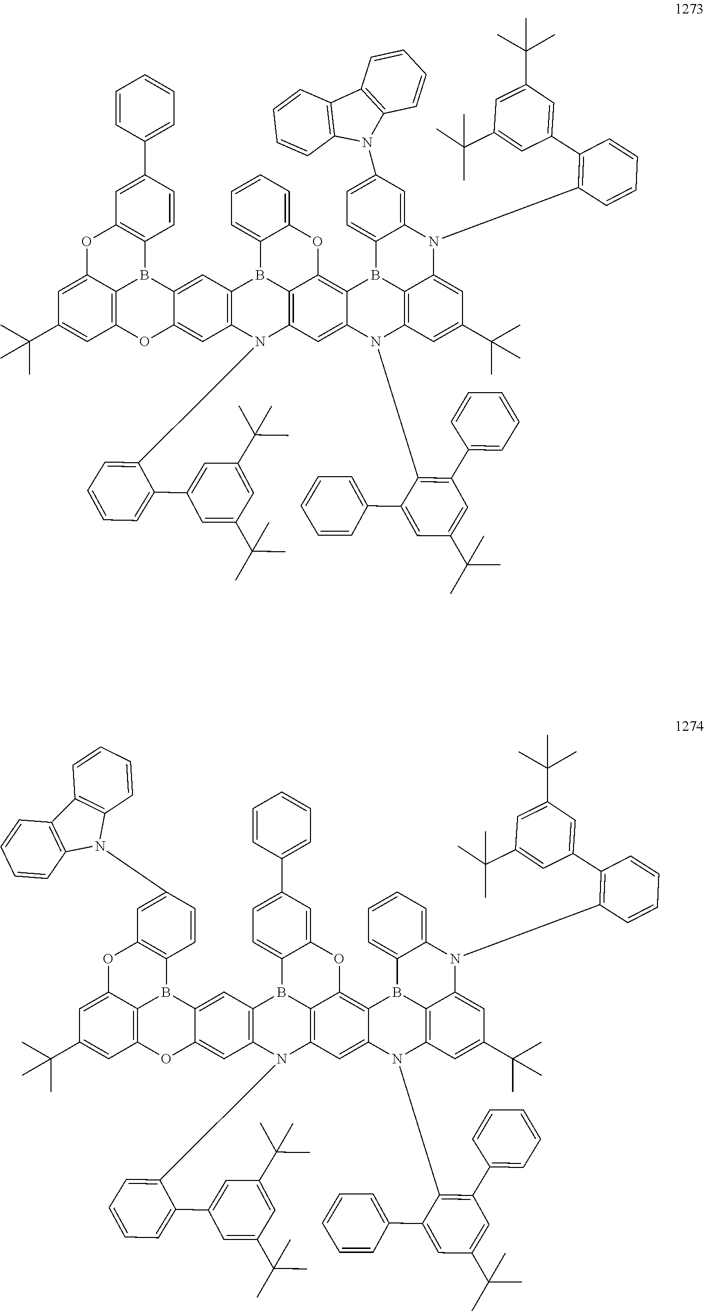 [SMILES: CC(C)(C)c1cc(-c2ccccc2N2c3cc(-n4c5ccccc5c5ccccc54)ccc3B3c4c2cc(C(C)(C)C)cc4N(c2c(-c4ccccc4)cc(C(C)(C)C)cc2-c2ccccc2)c2cc4c5c(c23)Oc2ccccc2B5c2cc3c(cc2N4c2ccccc2-c2cc(C(C)(C)C)cc(C(C)(C)C)c2)Oc2cc(C(C)(C)C)cc4c2B3c2ccc(-c3ccccc3)cc2O4)cc(C(C)(C)C)c1 ; CC(C)(C)c1cc(-c2ccccc2N2c3ccccc3B3c4c2cc(C(C)(C)C)cc4N(c2c(-c4ccccc4)cc(C(C)(C)C)cc2-c2ccccc2)c2cc4c5c(c23)Oc2cc(-c3ccccc3)ccc2B5c2cc3c(cc2N4c2ccccc2-c2cc(C(C)(C)C)cc(C(C)(C)C)c2)Oc2cc(C(C)(C)C)cc4c2B3c2ccc(-n3c5ccccc5c5ccccc53)cc2O4)cc(C(C)(C)C)c1]

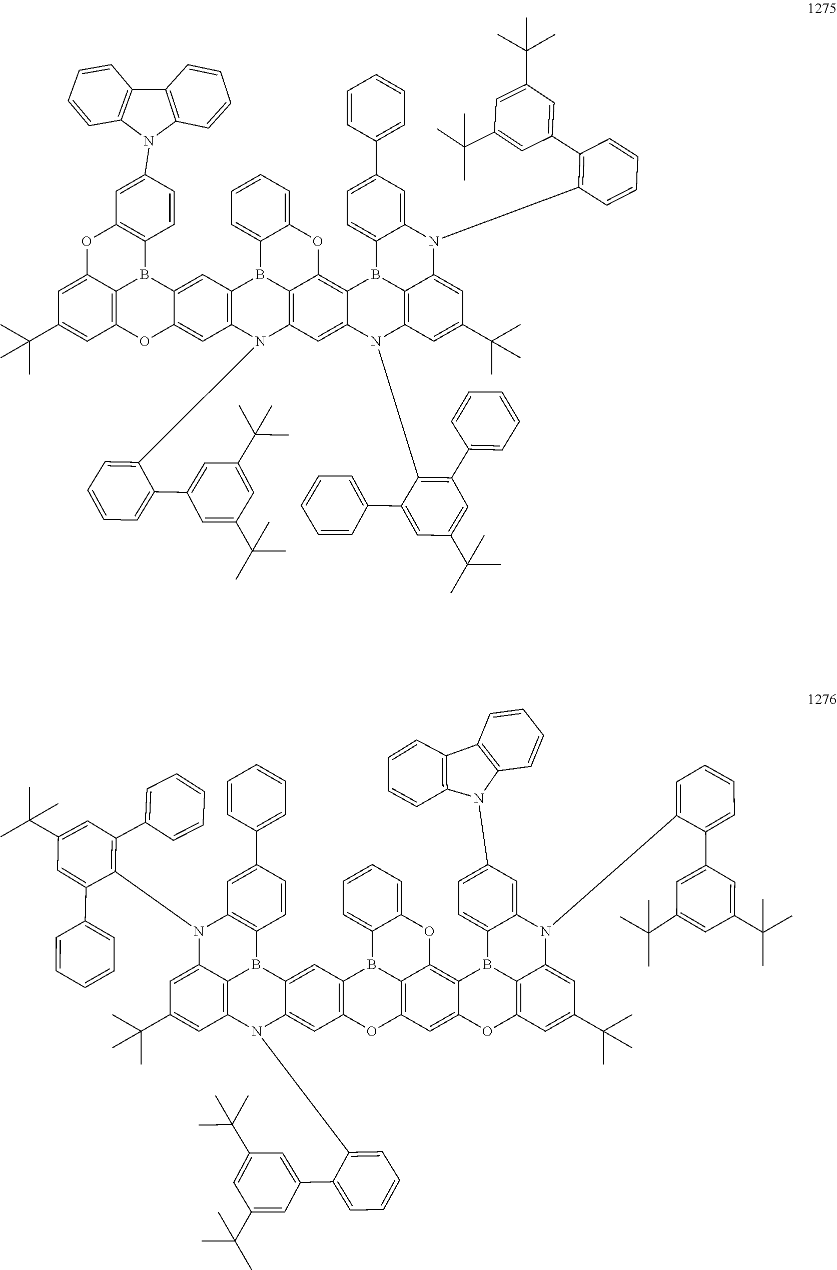

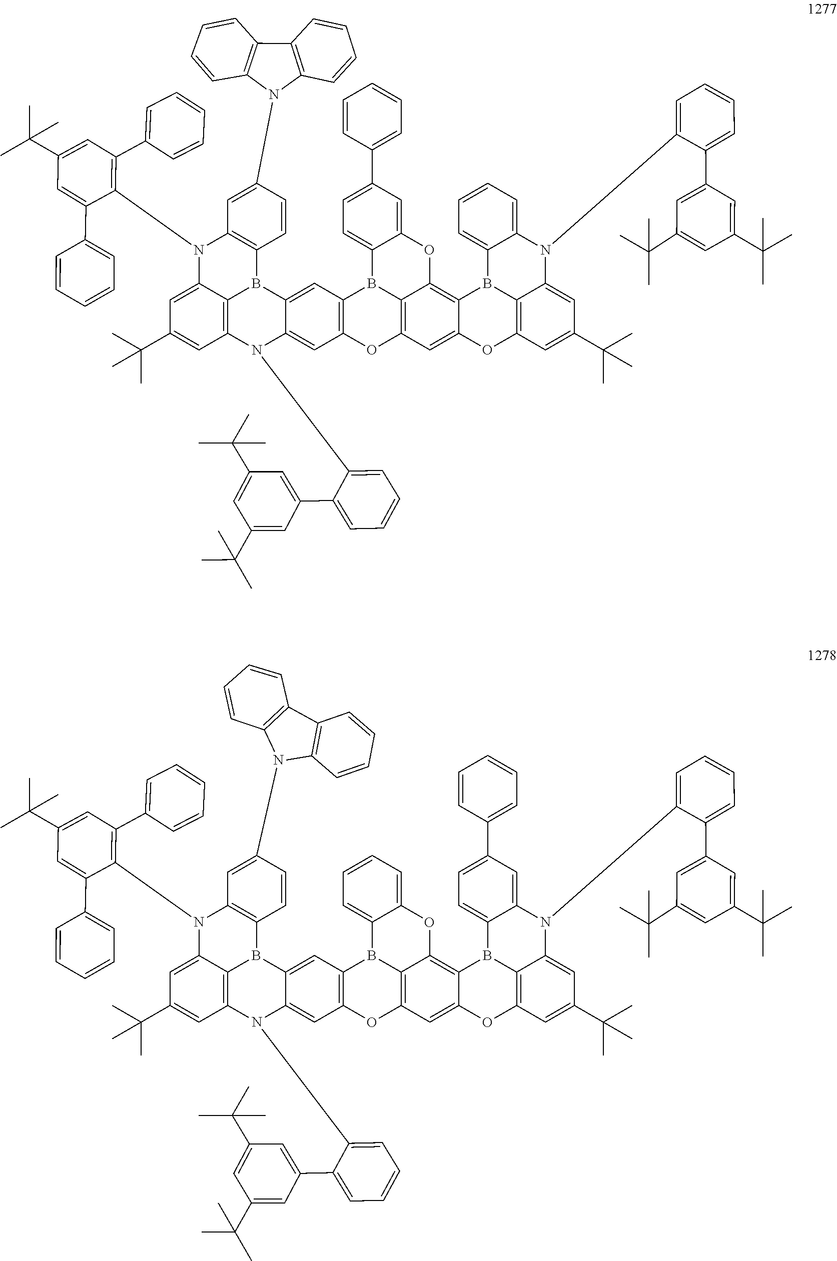

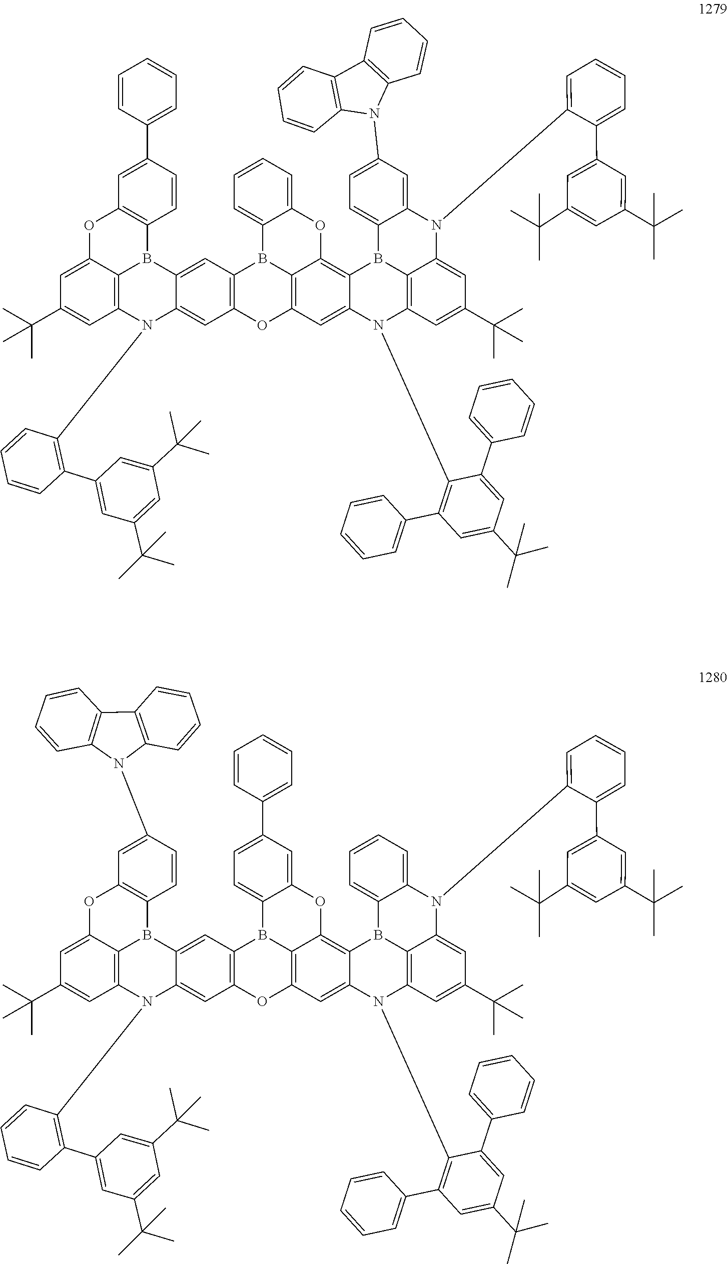

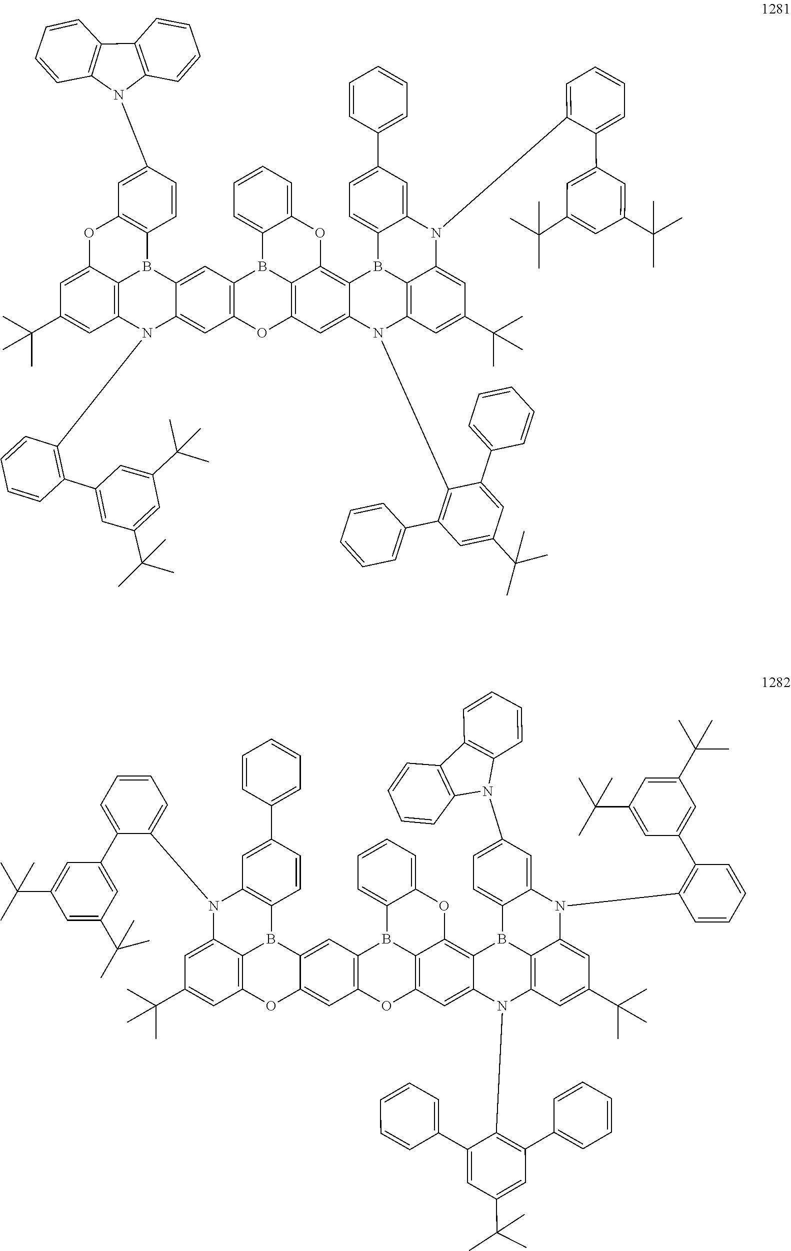

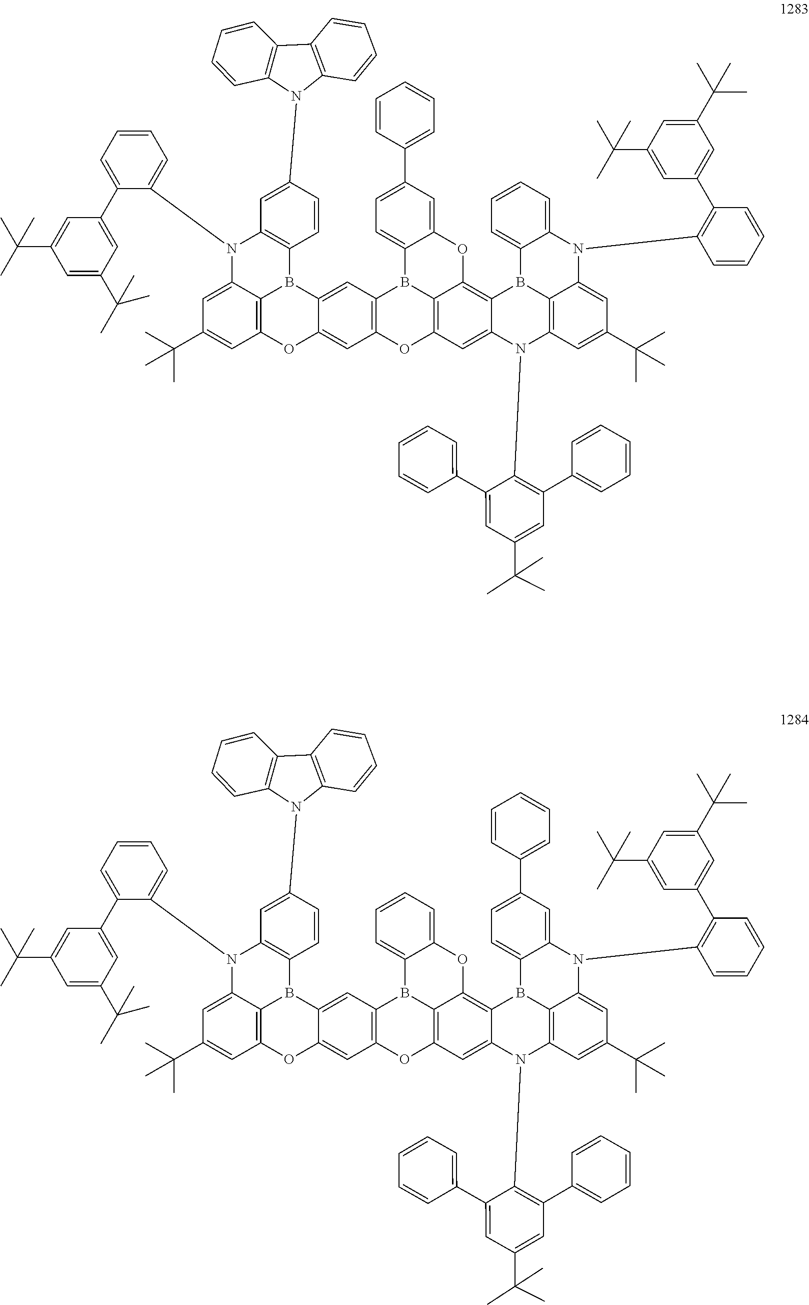

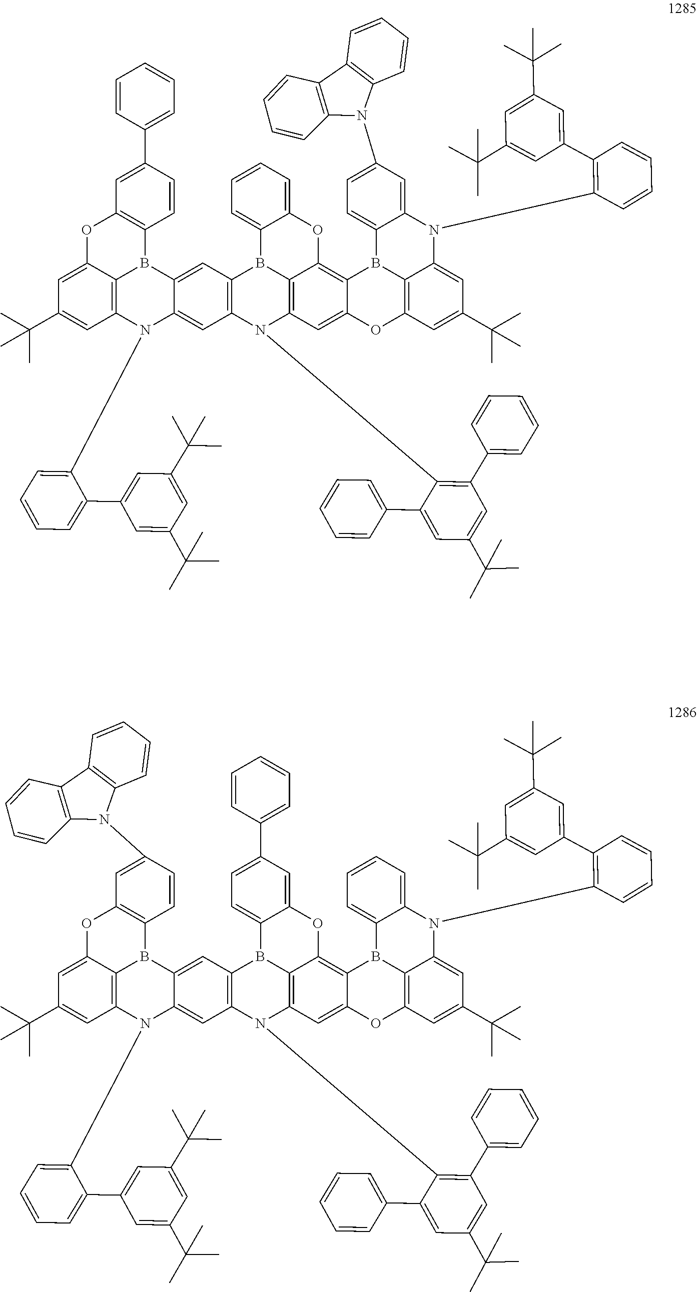 [SMILES: CC(C)(C)c1cc(-c2ccccc2N2c3cc4c(cc3B3c5ccc(-c6ccccc6)cc5Oc5cc(C(C)(C)C)cc2c53)B2c3ccccc3Oc3c5c(cc(c32)N4c2c(-c3ccccc3)cc(C(C)(C)C)cc2-c2ccccc2)Oc2cc(C(C)(C)C)cc3c2B5c2ccc(-n4c5ccccc5c5ccccc54)cc2N3c2ccccc2-c2cc(C(C)(C)C)cc(C(C)(C)C)c2)cc(C(C)(C)C)c1 ; CC(C)(C)c1cc(-c2ccccc2N2c3cc4c(cc3B3c5ccc(-n6c7ccccc7c7ccccc76)cc5Oc5cc(C(C)(C)C)cc2c53)B2c3ccc(-c5ccccc5)cc3Oc3c5c(cc(c32)N4c2c(-c3ccccc3)cc(C(C)(C)C)cc2-c2ccccc2)Oc2cc(C(C)(C)C)cc3c2B5c2ccccc2N3c2ccccc2-c2cc(C(C)(C)C)cc(C(C)(C)C)c2)cc(C(C)(C)C)c1]

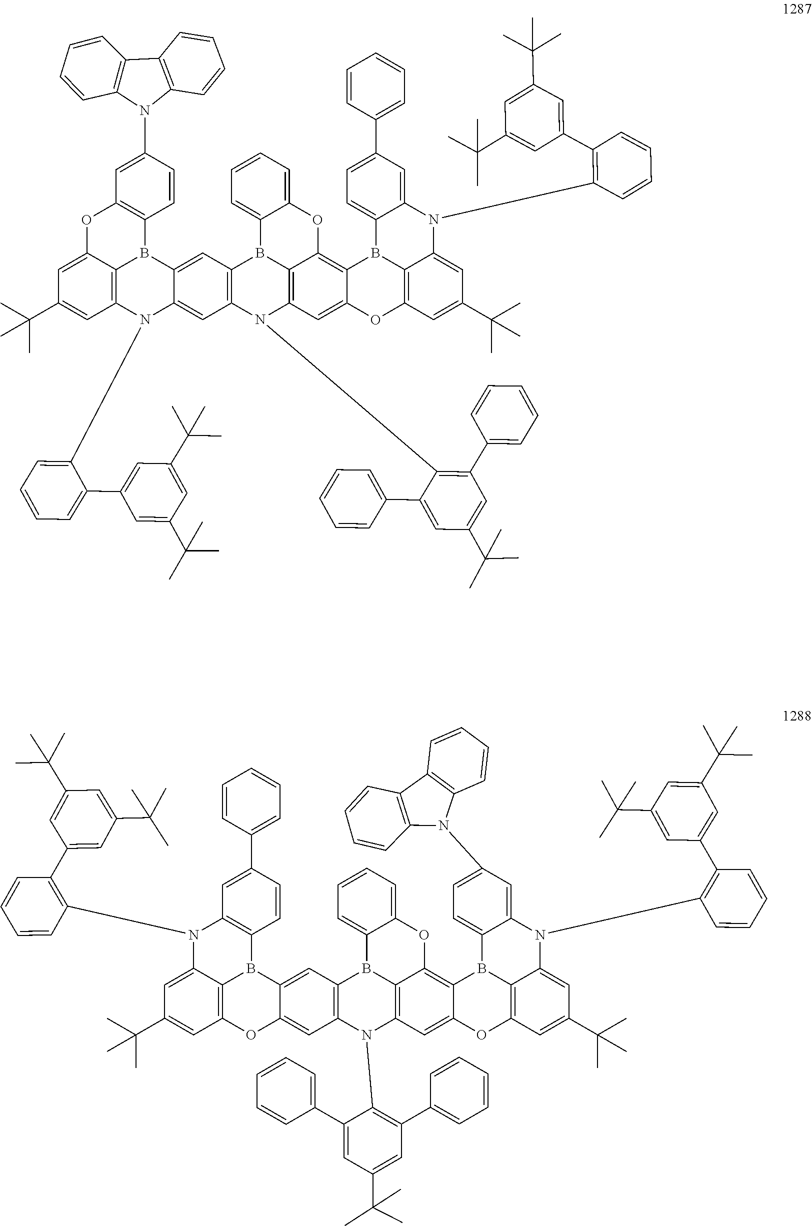

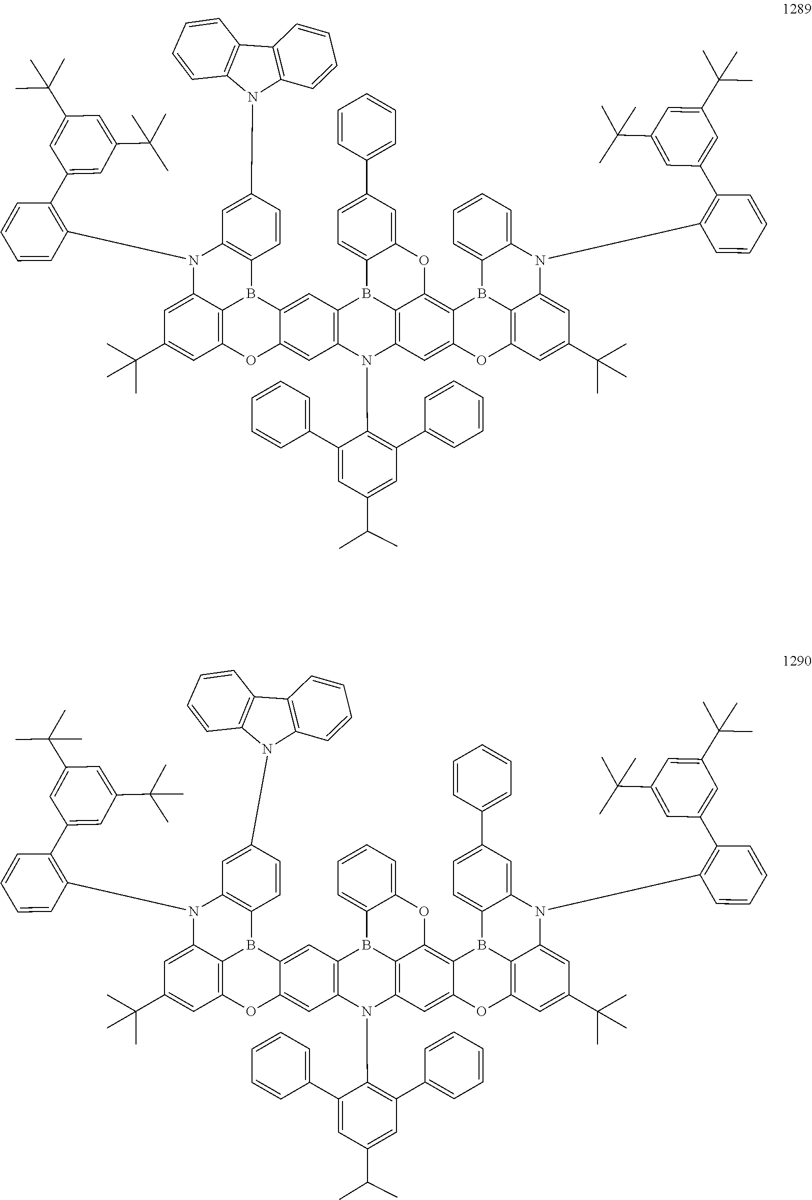

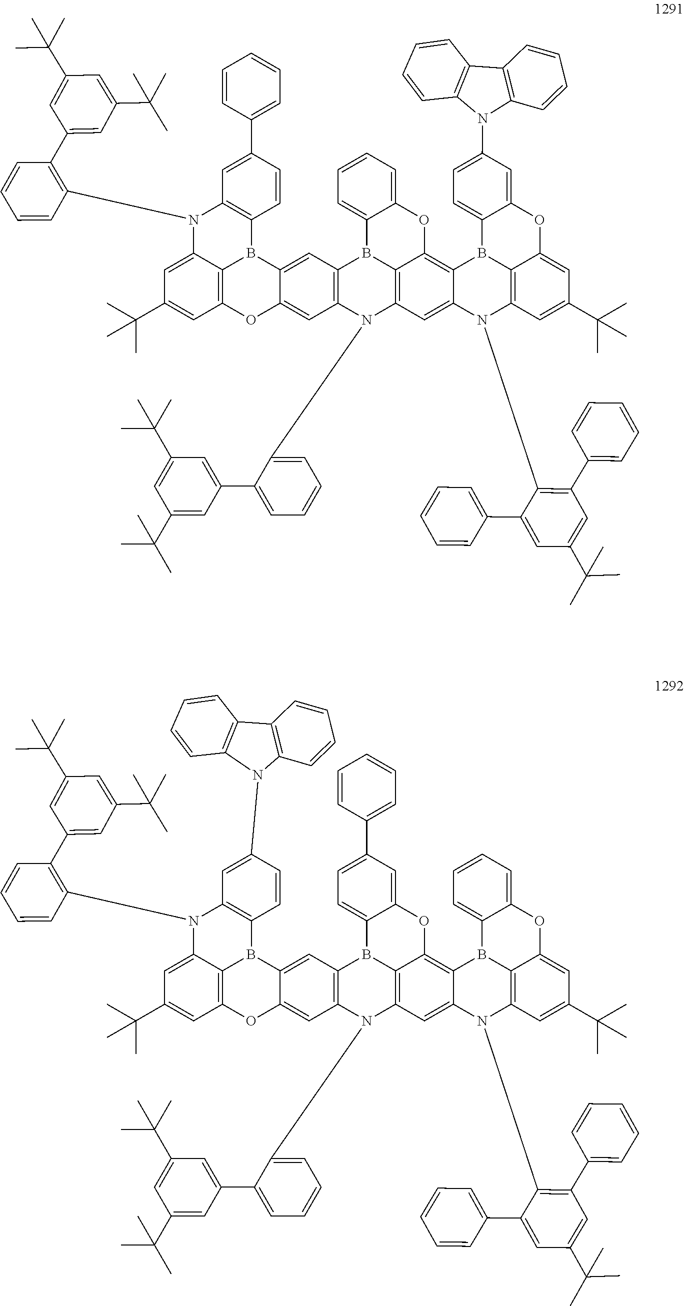

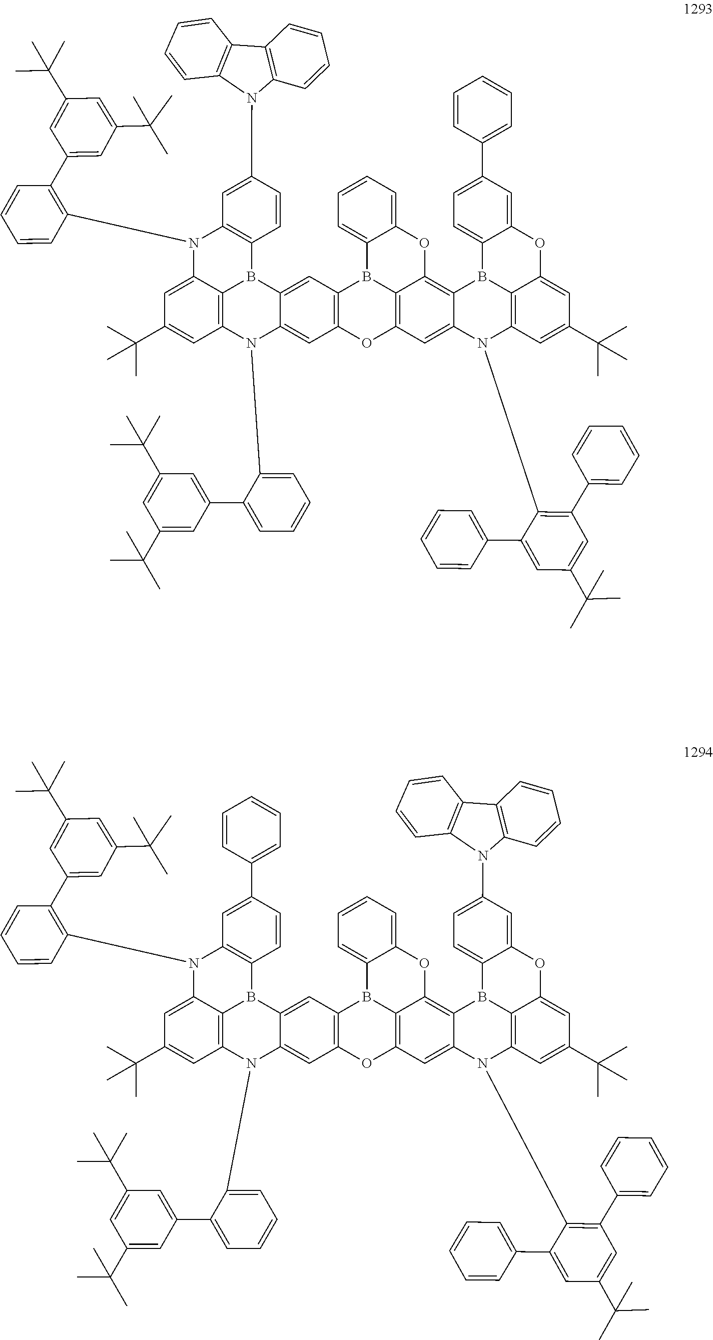

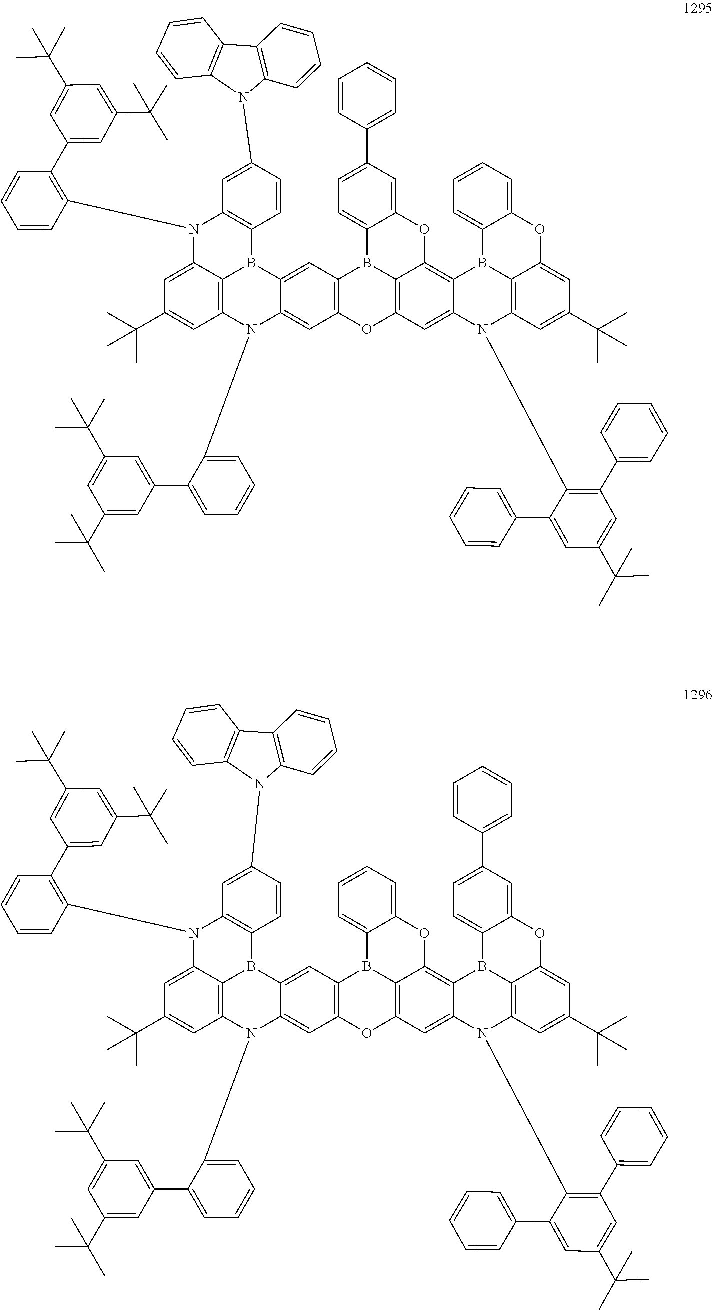

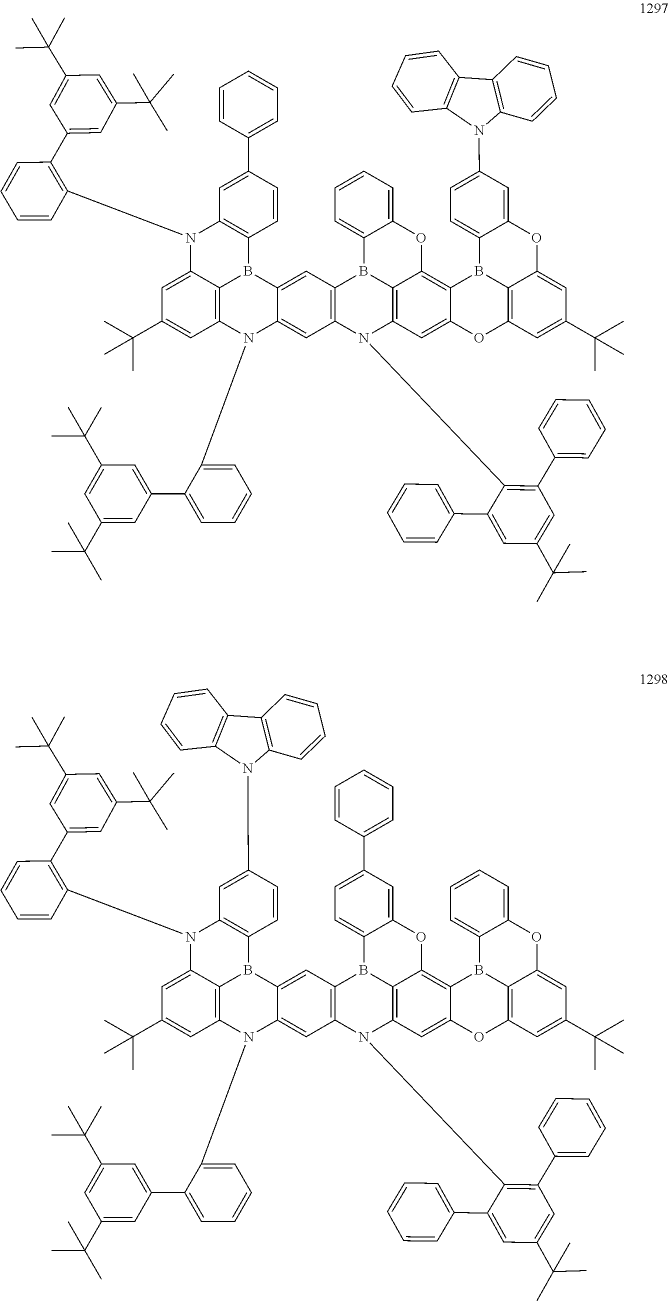

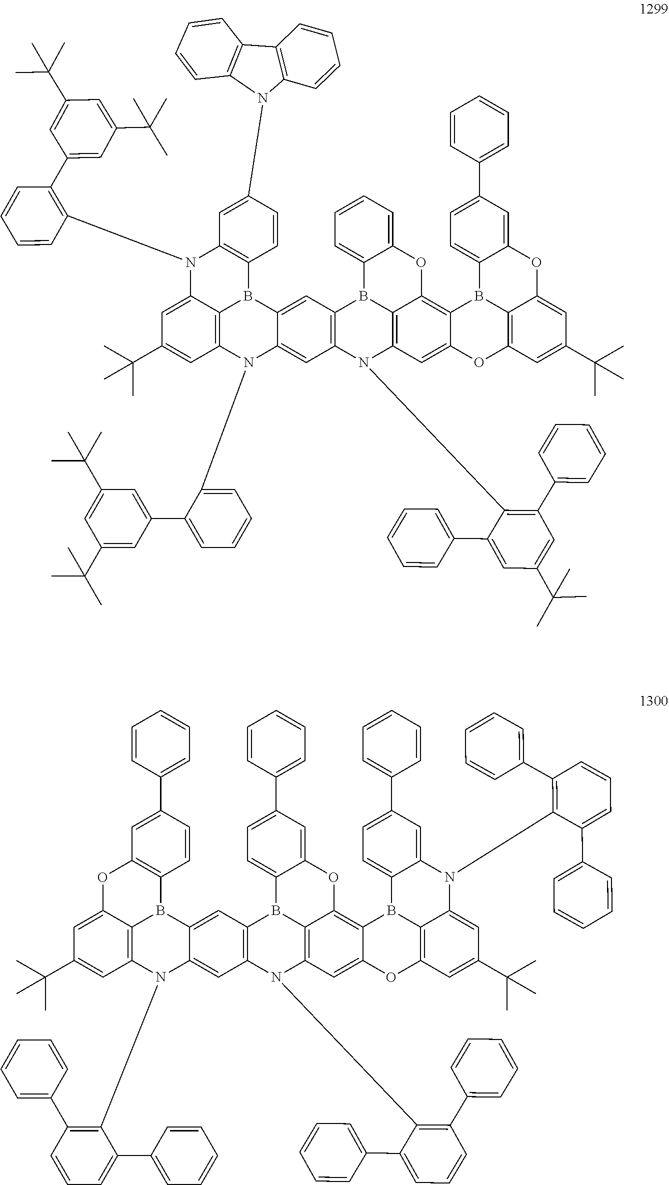 [SMILES: CC(C)(C)c1cc(-c2ccccc2N2c3cc(-n4c5ccccc5c5ccccc54)ccc3B3c4cc5c(cc4N(c4ccccc4-c4cc(C(C)(C)C)cc(C(C)(C)C)c4)c4cc(C(C)(C)C)cc2c43)N(c2c(-c3ccccc3)cc(C(C)(C)C)cc2-c2ccccc2)c2cc3c(c4c2B5c2ccccc2O4)B2c4ccc(-c5ccccc5)cc4Oc4cc(C(C)(C)C)cc(c42)O3)cc(C(C)(C)C)c1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1]

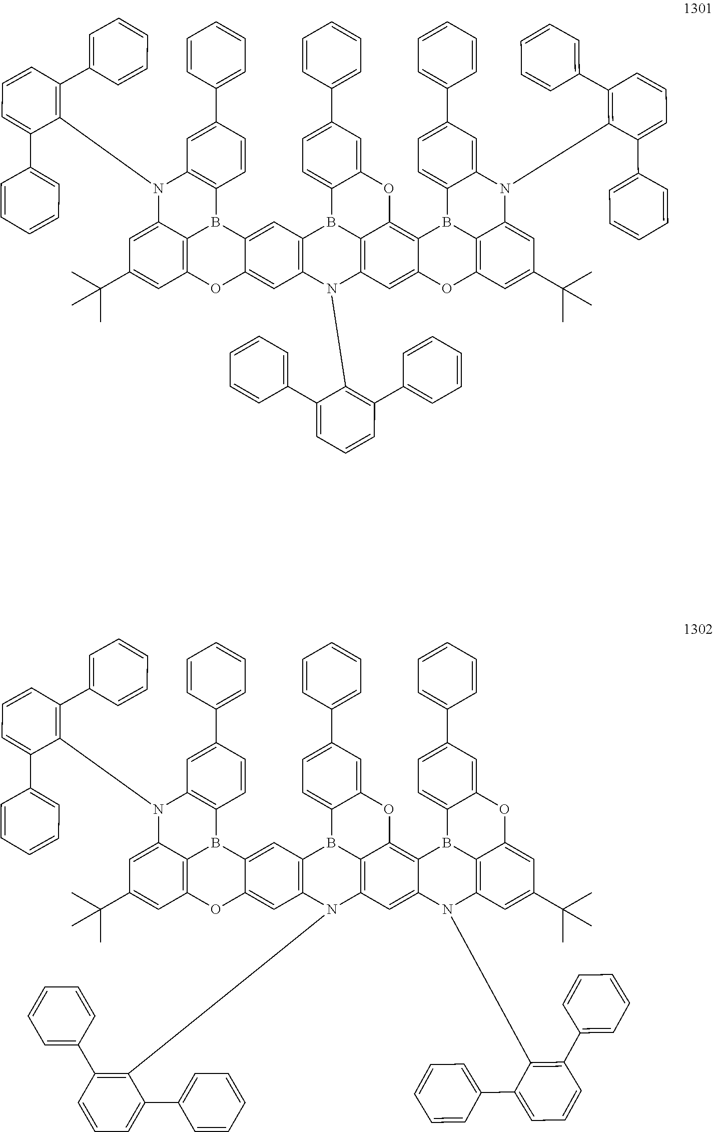 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3Oc3cc(C(C)(C)C)cc(c31)N2c1c(-c2ccccc2)cccc1-c1ccccc1]

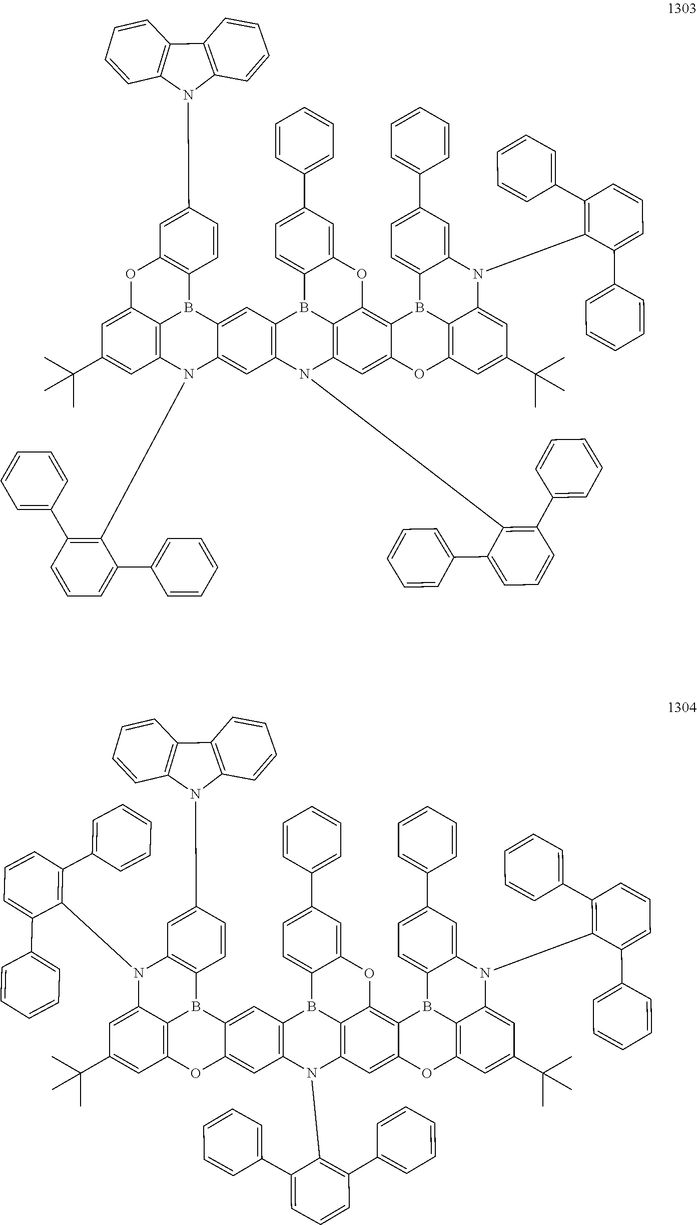 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3N(c3c(-c4ccccc4)cccc3-c3ccccc3)c3cc(C(C)(C)C)cc(c31)O2]

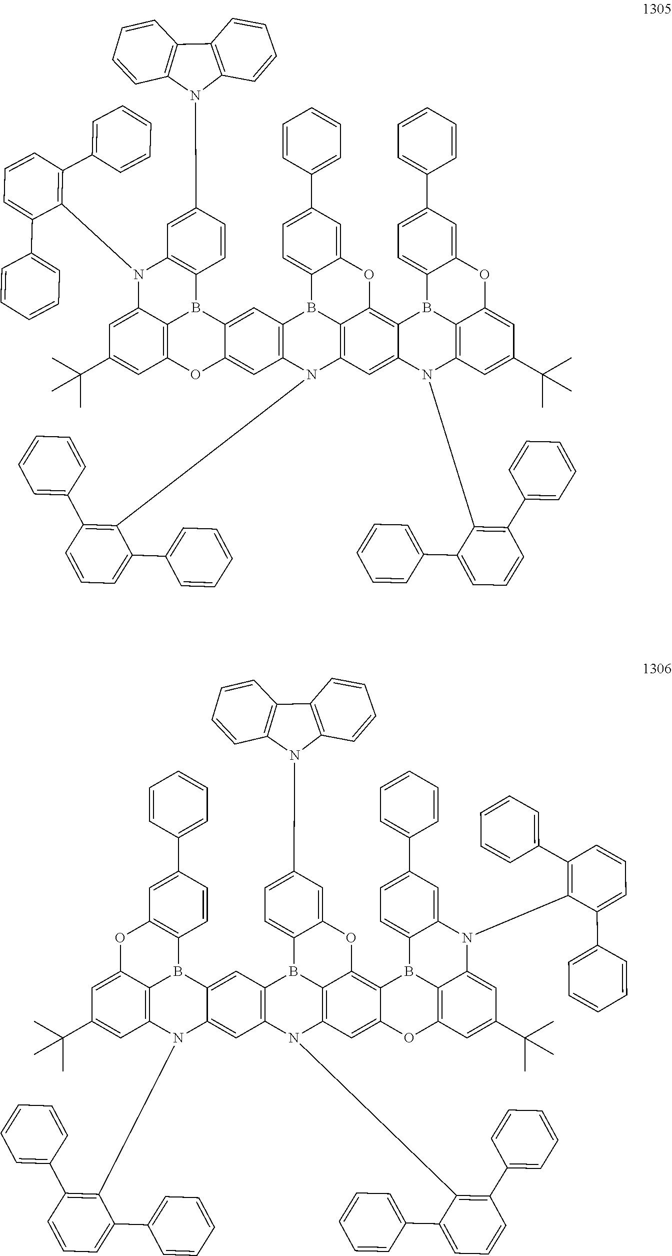 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-n3c5ccccc5c5ccccc53)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1]

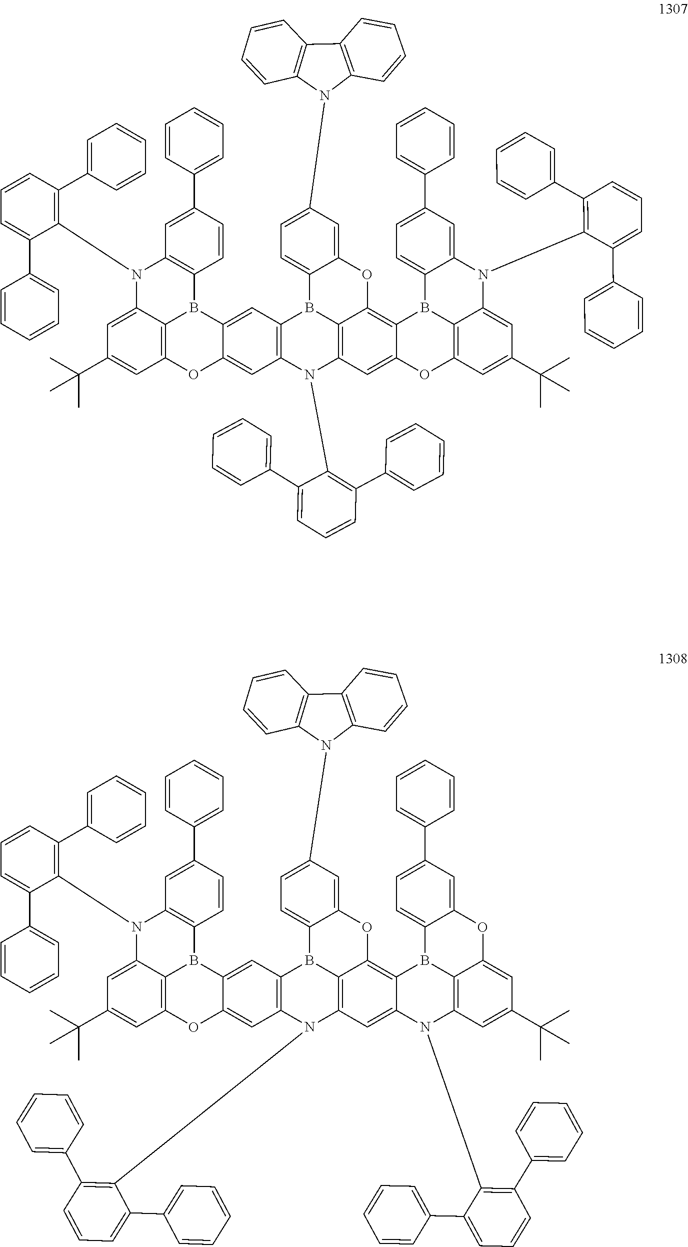 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-n3c5ccccc5c5ccccc53)cc1O4)B1c3ccc(-c4ccccc4)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-n3c5ccccc5c5ccccc53)cc1O4)B1c3ccc(-c4ccccc4)cc3Oc3cc(C(C)(C)C)cc(c31)N2c1c(-c2ccccc2)cccc1-c1ccccc1]

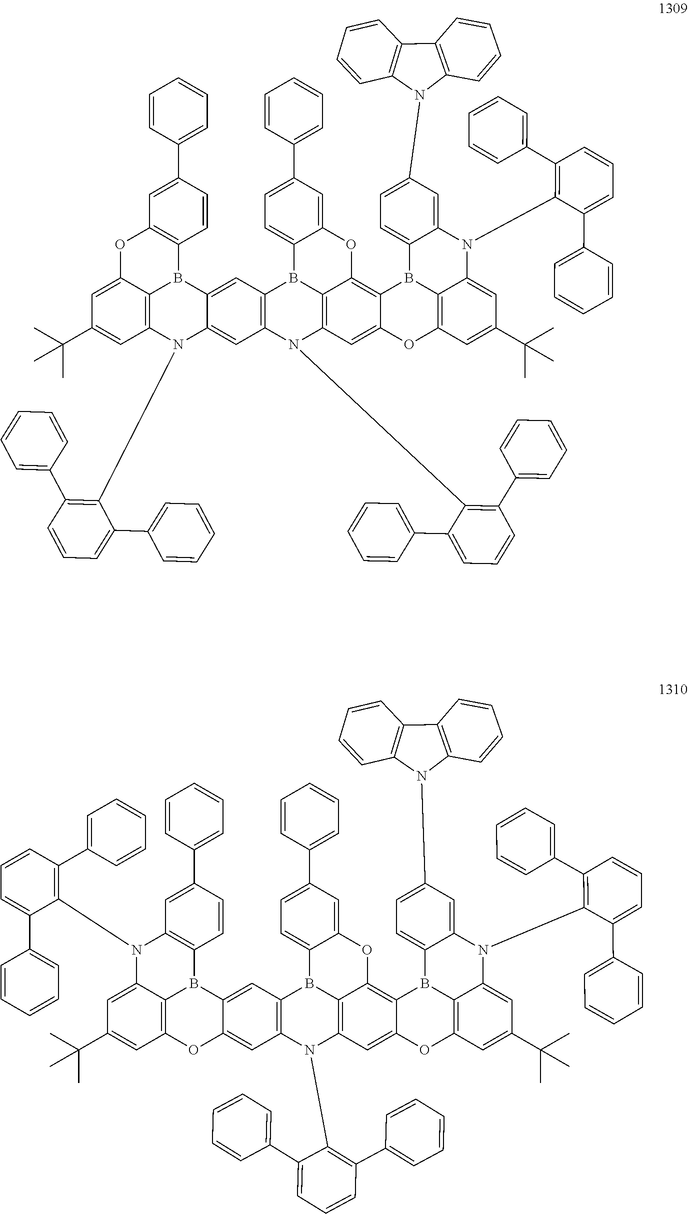 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3N(c3c(-c4ccccc4)cccc3-c3ccccc3)c3cc(C(C)(C)C)cc(c31)O2]

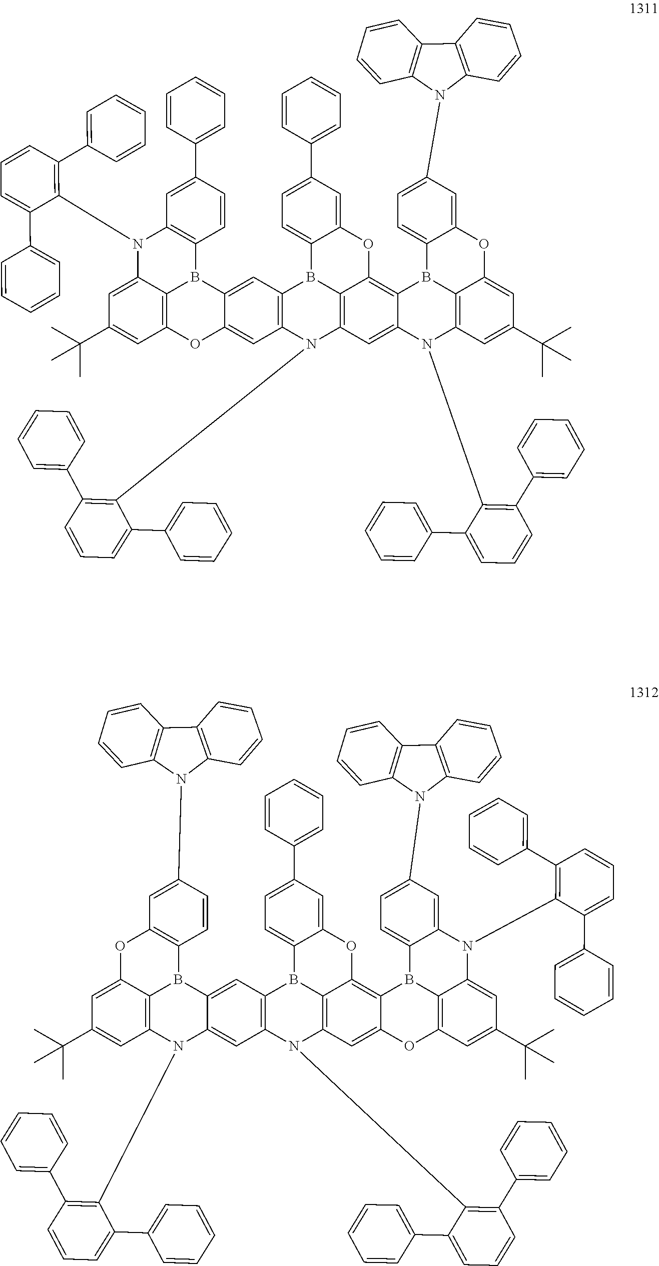 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-n3c4ccccc4c4ccccc43)cc1N2c1c(-c2ccccc2)cccc1-c1ccccc1]

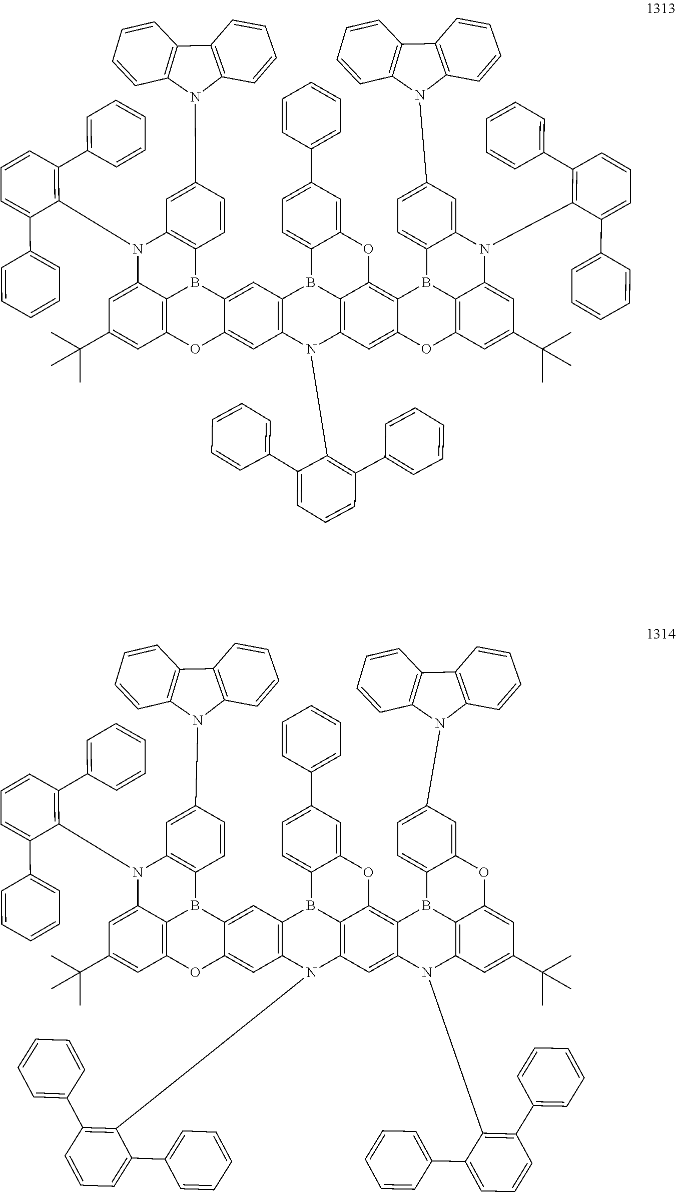 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3Oc3cc(C(C)(C)C)cc(c31)N2c1c(-c2ccccc2)cccc1-c1ccccc1]

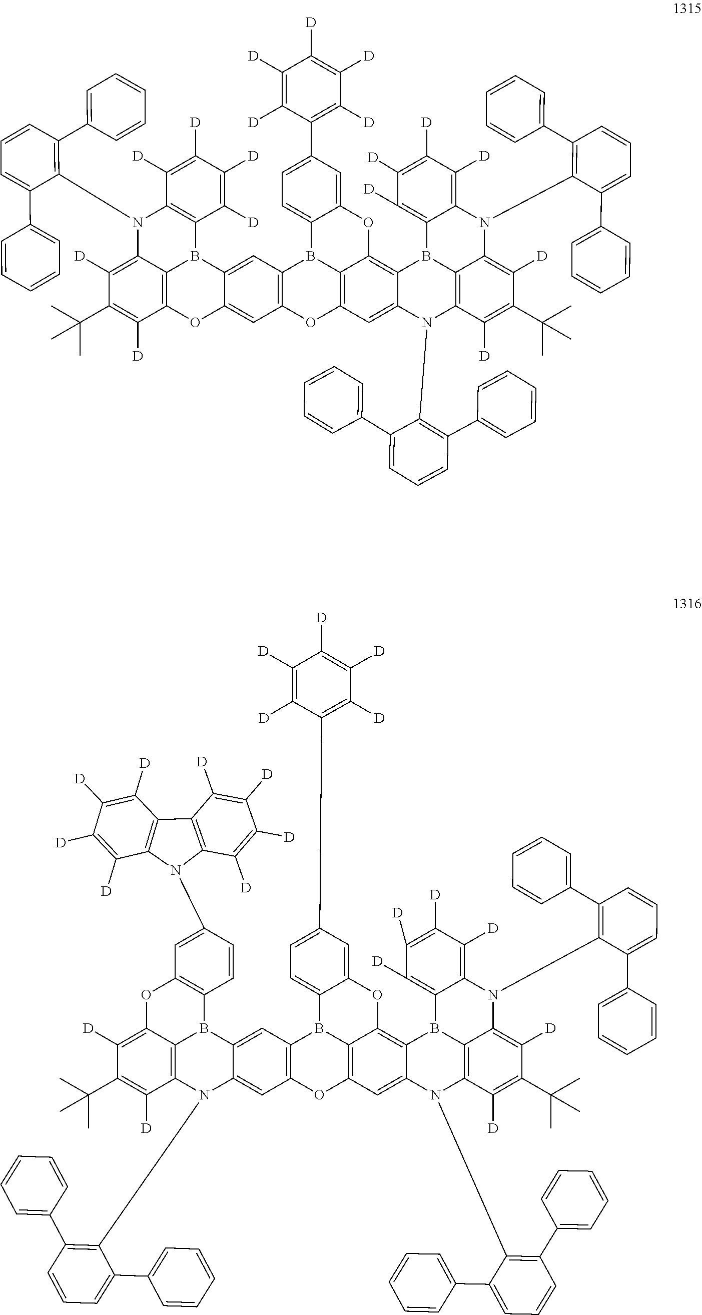

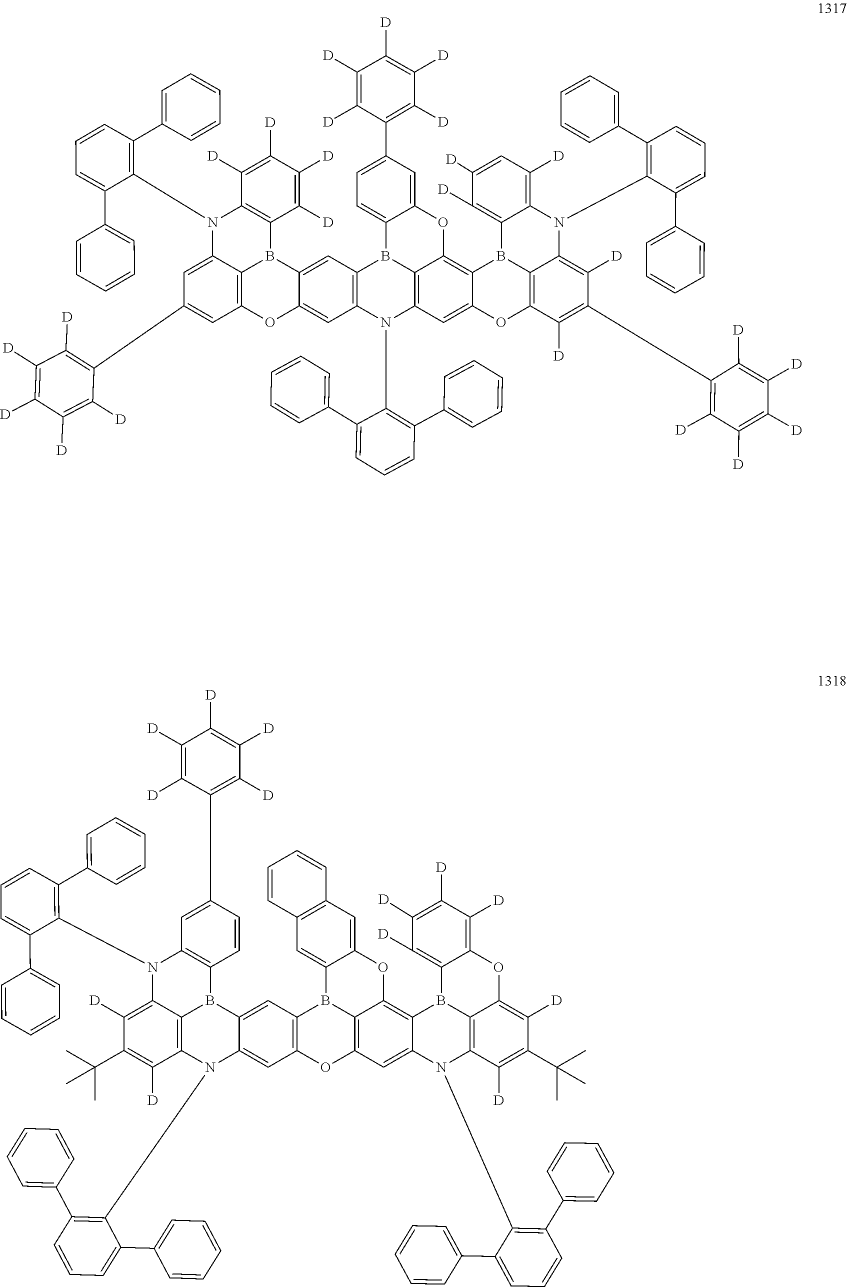

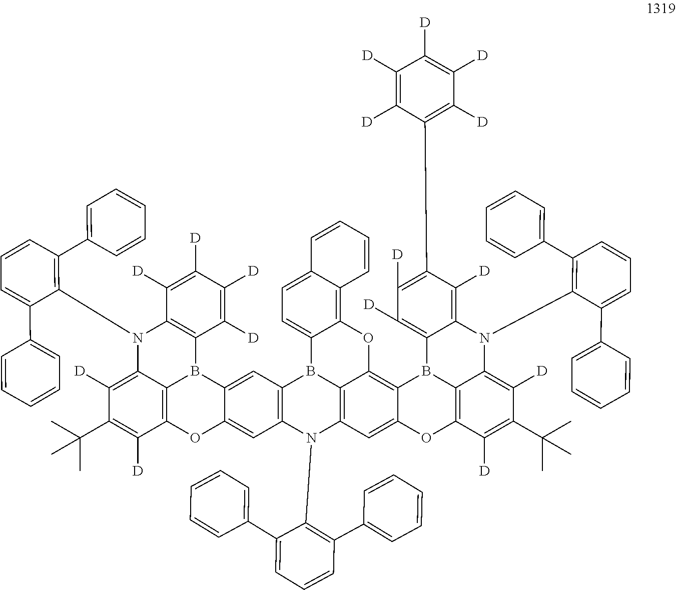 [SMILES: [2H]c1c([2H])c([2H])c(-c2c([2H])c([2H])c3c(c2[2H])N(c2c(-c4ccccc4)cccc2-c2ccccc2)c2c([2H])c(C(C)(C)C)c([2H])c4c2B3c2c(cc3c5c2Oc2c(ccc6ccccc26)B5c2cc5c(cc2N3c2c(-c3ccccc3)cccc2-c2ccccc2)Oc2c([2H])c(C(C)(C)C)c([2H])c3c2B5c2c([2H])c([2H])c([2H])c([2H])c2N3c2c(-c3ccccc3)cccc2-c2ccccc2)O4)c([2H])c1[2H]]

The light emitting element ED including the fused polycyclic compound according to one or more embodiments may have a central emission wavelength in a wavelength range of about 450 nm to about 470 nm. The central emission wavelength may indicate a wavelength at a point of which maximum emission intensity in an emission spectrum. The light emitting element ED including the fused polycyclic compound according to one or more embodiments may be to emit blue color light. In one or more embodiments, the third light emitting element ED-3 (FIG. 2) emitting blue color light may include the fused polycyclic compound according to one or more embodiments.

The emission layer EML may include the fused polycyclic compound according to one or more embodiments as a dopant. The fused polycyclic compound according to one or more embodiments may be a delayed fluorescence material. The fused polycyclic compound according to one or more embodiments may be a material of thermally activated delayed fluorescence (TADF). In one or more embodiments, the fused polycyclic compound according to one or more embodiments may be to emit light through a reverse intersystem crossing (RISC) mechanism, which converts triplet excitons into singlet excitons.

The fused polycyclic compound according to one or more embodiments may include, as a central structure (e.g., core structure or skeleton structure), a fused ring of 13 rings, which contains three boron atoms and six heteroatoms as ring-forming atoms. In addition, the fused polycyclic compound according to one or more embodiments may include at least one substituent that is bonded to the central structure and is not hydrogen. The at least one substituent may correspond to R^{x1} of Formula 1 described above. The at least one substituent may correspond to at least one group selected from among R¹ to R²¹ of Formula 2 described above. The fused polycyclic compound according to one or more embodiments may include, as a central structure, a fused ring of 13 rings represented by Formula Z1. In Formula Z1, the same descriptions as in Formula 1 may be applied to Y¹ to Y⁶. In Formula Z1, ‘MT-1’ and ‘MT-2’ are indicated for convenience of description.

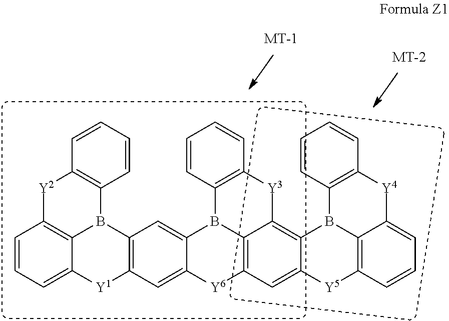

In Formula Z1, MT-1 may be moiety having acceptor properties and MT-2 may be a moiety having donor properties. In addition, MT-1 is a moiety in which LUMO orbital is distributed, and MT-2 is a moiety in which HOMO orbital is distributed. In one or more embodiments, the fused polycyclic compound according to one or more embodiments is of the 3B-MRCT type (kind). The 3B-MRCT type (kind) contains HOMO-1B and LUMO-2B, in which the HOMO orbital is distributed on one of the three boron atoms as ring-forming atoms, and the LUMO orbital is distributed on the other two boron atoms. As such, the fused polycyclic compound according to one or more embodiments including a moiety having donor characteristics and a moiety having acceptor characteristics and having the HOMO orbital and the LUMO orbital separated may have improved multiple resonance (MR) characteristics and stokes-shift characteristics. The fused polycyclic compound according to one or more embodiments including a structure represented by Formula Z1 as a central structure may exhibit strong emission intensity and high absorbance, and may contribute to improving lifespan of the light emitting element ED through rapid reverse intersystem crossing.

Typical compounds including a fused ring of nine rings containing two boron atoms as ring-forming atoms, as a central structure, have excitons that remain in the triplet state for long periods of time, which reduces the lifespan of the light emitting element. In addition, typical compounds including a fused ring of nine rings as a central structure have heteroatoms other than nitrogen atoms introduced into the central structure, resulting in deterioration of some of multiple resonance characteristics. Typical compounds including a fused ring of nine rings as a central structure are of the 2B-MRCT type (kind). The 2B-MRCT type (kind) contains HOMO-1B and LUMO-1B, in which the HOMO orbital is distributed on one of the two boron atoms as ring-forming atoms, and the LUMO orbital is distributed on the other one boron atom. Accordingly, the typical compounds exhibit a value of large stokes-shift and emit light with reduced color purity. The stokes-shift indicates a value of a difference between a maximum wavelength (e.g., maximum absorption wavelength) when energy is absorbed and a maximum wavelength (e.g., maximum emission wavelength) when energy is emitted. Typical compounds exhibit a relatively uniform distribution of HOMO and LUMO orbitals, without separation. The typical compounds exhibiting a relatively uniform distribution of HOMO and LUMO orbitals are of the MR (multiple resonance) type (kind), rather than the CT type (kind).

The fused ring of nine rings included in typical compounds is represented by Formula Z-2. In Formula Z-2, ‘MT-3’ and ‘MT-4’ are indicated for convenience of description. MT-3 is a moiety in which LUMO orbital is distributed, and MT-4 is a moiety in which HOMO orbital is distributed.

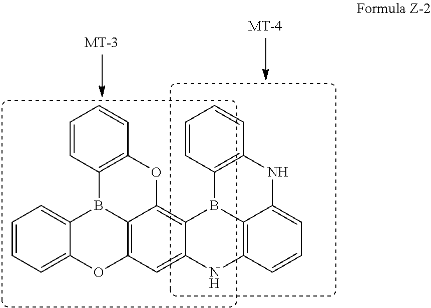 [SMILES: c1ccc2c(c1)Nc1cccc3c1B2c1c(cc2c4c1Oc1ccccc1B4c1ccccc1O2)N3]

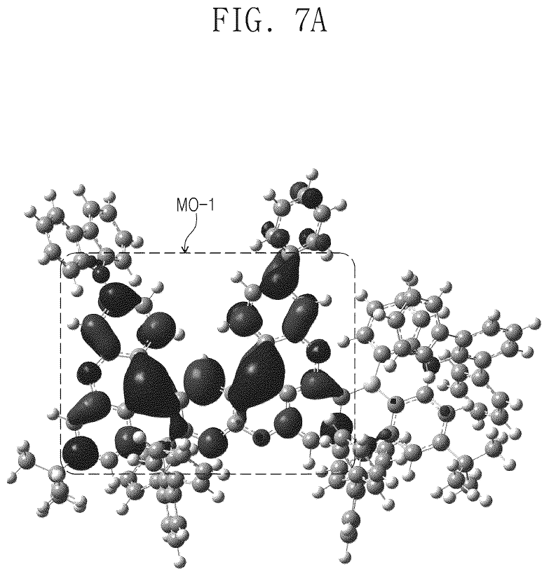

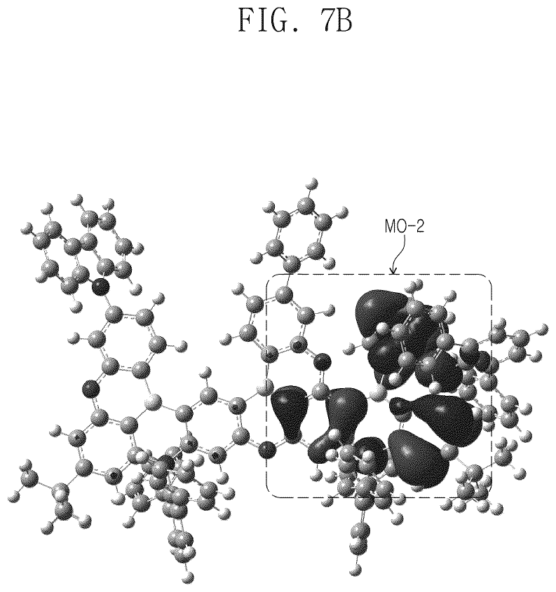

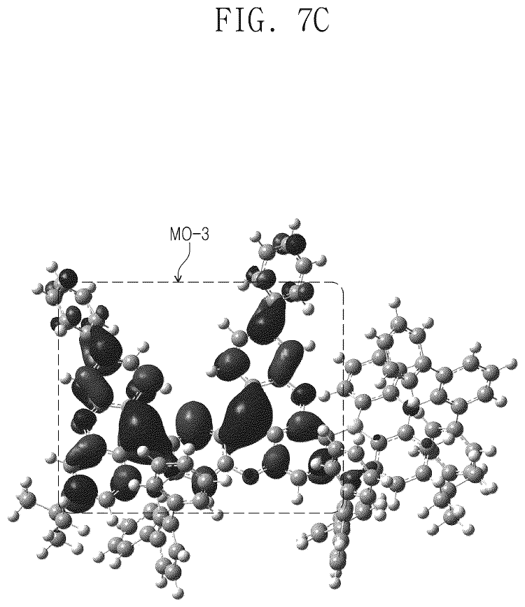

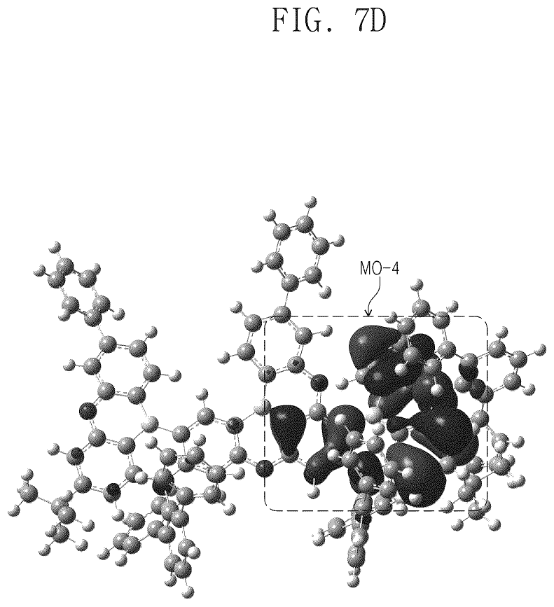

FIG. 7A is an image showing lowest unoccupied molecular orbital (LUMO) distribution of Compound 503. FIG. 7B is an image showing highest occupied molecular orbital (HOMO) distribution of Compound 503. FIG. 7C is an image showing LUMO distribution of Compound 1117. FIG. 7D is an image showing HOMO distribution of Compound 1117. Compounds 503 and 1117 are each a fused polycyclic compound according to an embodiment, each containing a fused ring of 13 rings as a central structure. In Compounds 503 and 1117 shown below, ‘MO-1’ to ‘MO-4’ are indicated for convenience of description and correspond to ‘MO-1’ to ‘MO-4’ of FIGS. 7A to 7D.

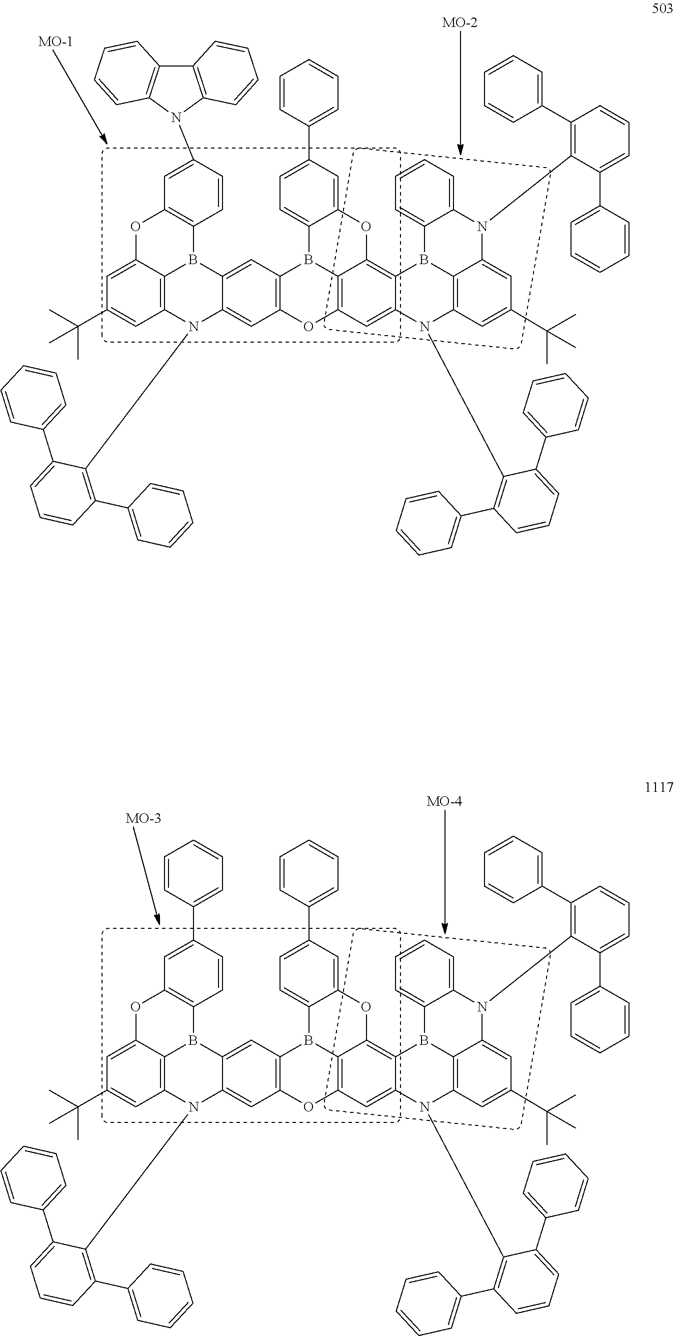

Referring to FIGS. 7A and 7B, it is seen that the HOMO and LUMO orbitals are separated in Compound 503. It is seen that in Compound 503, the HOMO orbital distribution is concentrated on the boron atom relatively to the right of the central structure, and the LUMO orbital distribution is concentrated on the boron atom relatively to the left of the central structure. In addition, referring to FIGS. 7C and 7D, it is seen that the HOMO and LUMO orbitals are separated in Compound 1117. It is seen that in Compound 1117, the HOMO orbital distribution is concentrated on the boron atom relatively to the right of the central structure, and the LUMO orbital distribution is concentrated on the boron atom relatively to the left of the central structure. In addition, in Compounds 503 and 1117, it is seen that the HOMO orbital and the LUMO orbital are each conjugated. In one or more embodiments, the fused polycyclic compound according to one or more embodiments may be a charge-transfer type (kind) (CT) in which the HOMO orbital and the LUMO orbital are separated. Accordingly, it is seen that the fused polycyclic compound according to one or more embodiments may exhibit strong emission intensity and high absorbance, and may contribute to improving lifespan of the light emitting element ED through rapid reverse intersystem crossing.

Table 1 is a computation result that evaluates the properties of a compound. In Table 1, S1_V indicates an energy level value in a lowest singlet (S1) state of the compound, and T1_V indicates an energy level value in a lowest triplet (T1) state of the compound. AEST indicates an absolute value of a difference in energy level between the S1 state and the T1 state of the compound. OSC indicates oscillator strength of the compound, and HOMO_V indicates HOMO energy level of the compound. Comparative Example Compound X-1 is shown below. Compounds 398, 503, and 1117 are fused polycyclic compounds according to one or more embodiments.

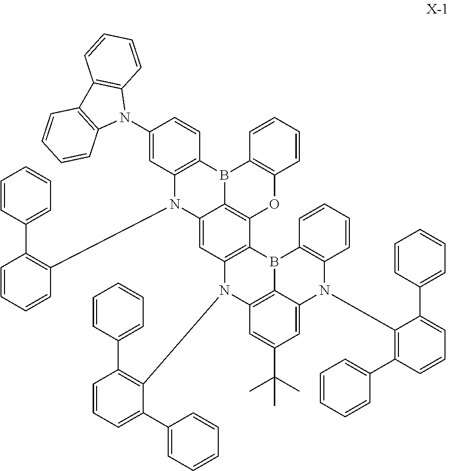 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1ccc(-n2c3ccccc3c3ccccc32)cc1N4c1ccccc1-c1ccccc1]

TABLE 1

| | S1_V | T1_V | ΔE_{ST} | | HOMO_V |
|---|---|---|---|---|---|
| compound | (eV) | (eV) | (eV) | OSC | (eV) |
| Compound 398 | 2.86 | 2.66 | 0.20 | 0.286 | −4.84 |
| Compound 503 | 2.83 | 2.63 | 0.20 | 0.280 | −4.82 |
| Compound 1117 | 2.85 | 2.63 | 0.22 | 0.312 | −4.80 |
| Comparative | 2.88 | 2.63 | 0.25 | 0.158 | −4.82 |
| Example | | | | | |
| Compound X-1 | | | | | |

Referring to Table 1, it is seen that, compared to Comparative Example Compound X-1, Compounds 398, 503, and 1117 each exhibit a small AEST and a large OSC. Compounds 398, 503, and 1117 are fused polycyclic compounds according to one or more embodiments, each of which contains the fused ring of 13 rings described above as a central structure. Accordingly, it is seen that the fused polycyclic compound according to one or more embodiments exhibits a small AEST and a large OSC.

Comparative Example Compound X-1 contains a fused ring of nine rings as a central structure, which is different from the fused ring of 13 rings included in the fused polycyclic compound according to one or more embodiments. Accordingly, it is considered that Comparative Example Compound X-1 exhibited a relatively large AEST and a small OSC.

In one or more embodiments, the emission layer EML may include the fused polycyclic compound according to one or more embodiments, and further include at least one selected from among second to fourth compounds. In one or more embodiments, the emission layer EML may include a second compound represented by Formula HT-1. For example, the second compound may be used as a hole transporting host material in the emission layer EML.

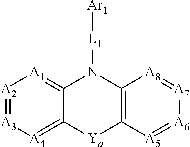

In Formula HT-1, A₁ to A₈ may each independently be N or CR₅₁. For example, in one or more embodiments, all of A₁ to A₈ may be CR₅₁. In one or more embodiments, any one selected from among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that the two 6-membered rings (e.g., two benzene rings) linked to the nitrogen atom in Formula HT-1 are linked via a direct linkage,

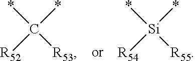

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may each independently be bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The emission layer EML may include at least one selected from among the compounds represented by Compound Group 2 as a hole transporting host material.

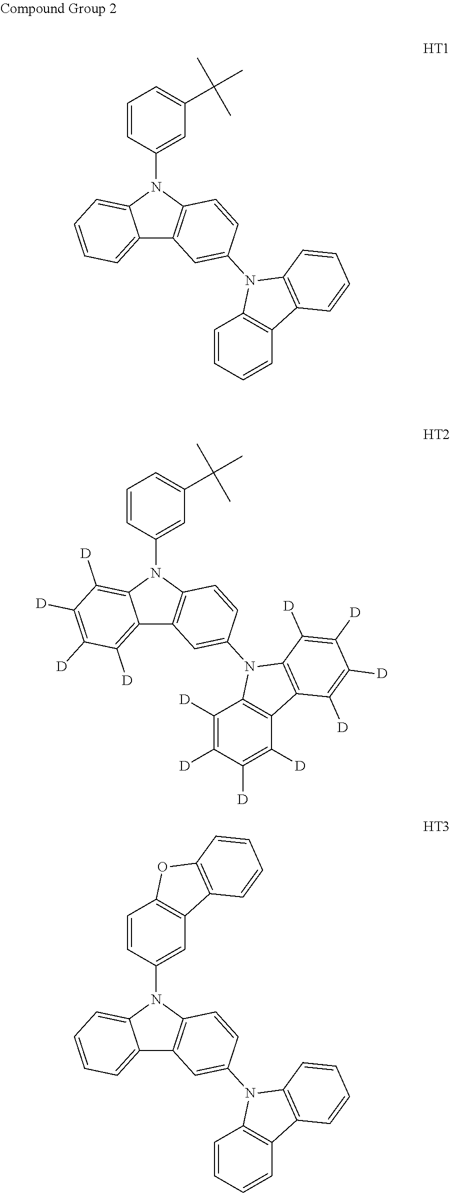

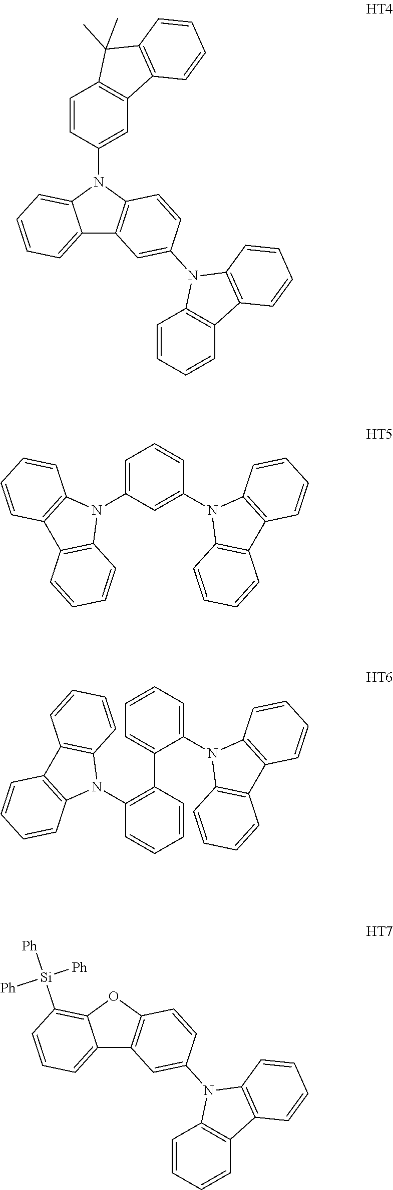 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

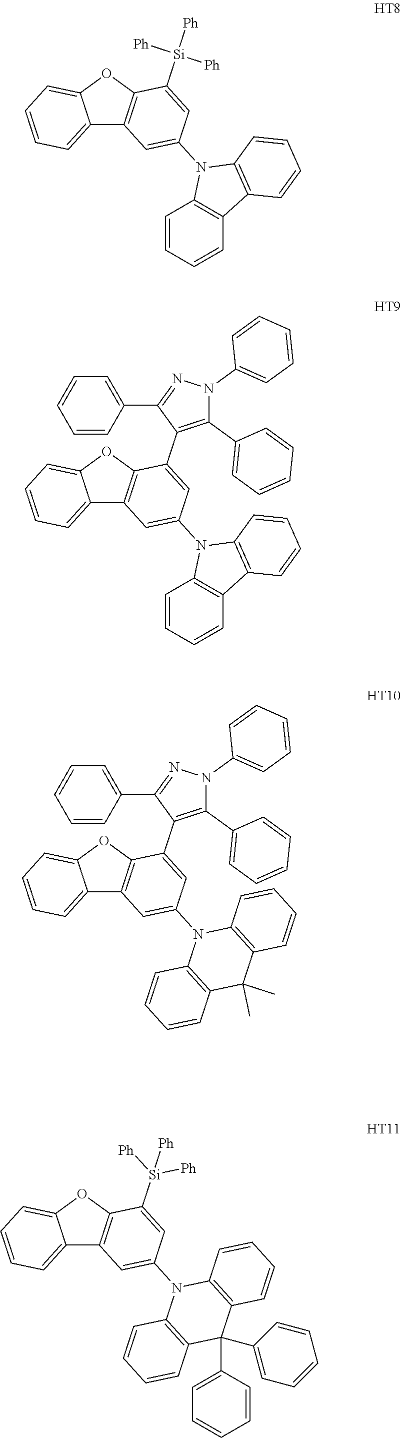 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

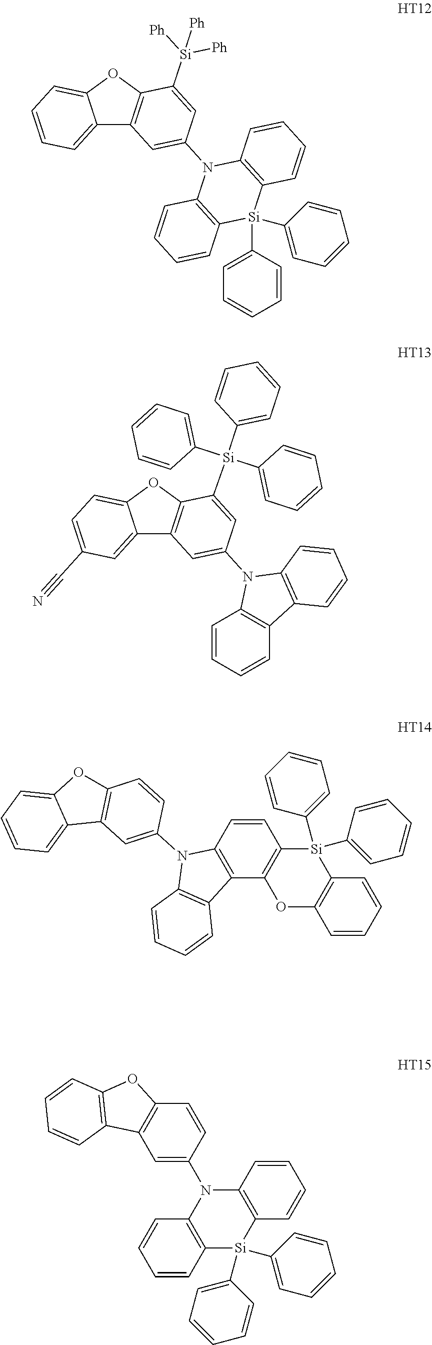

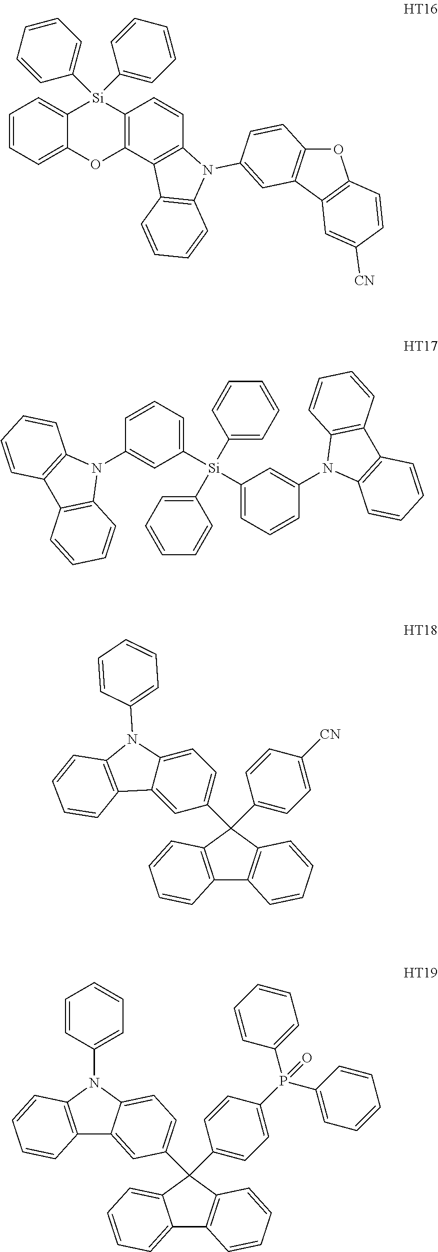 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

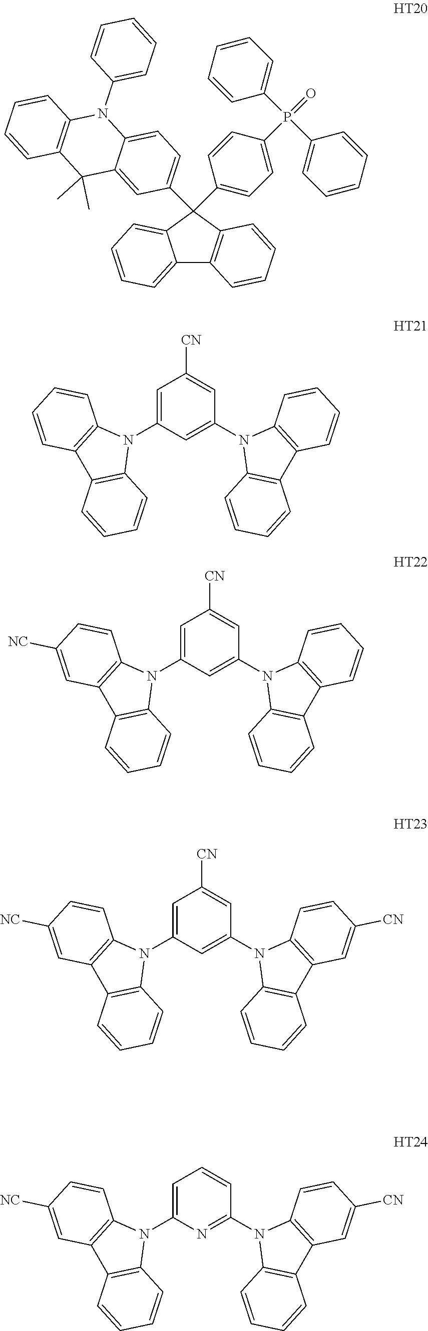 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

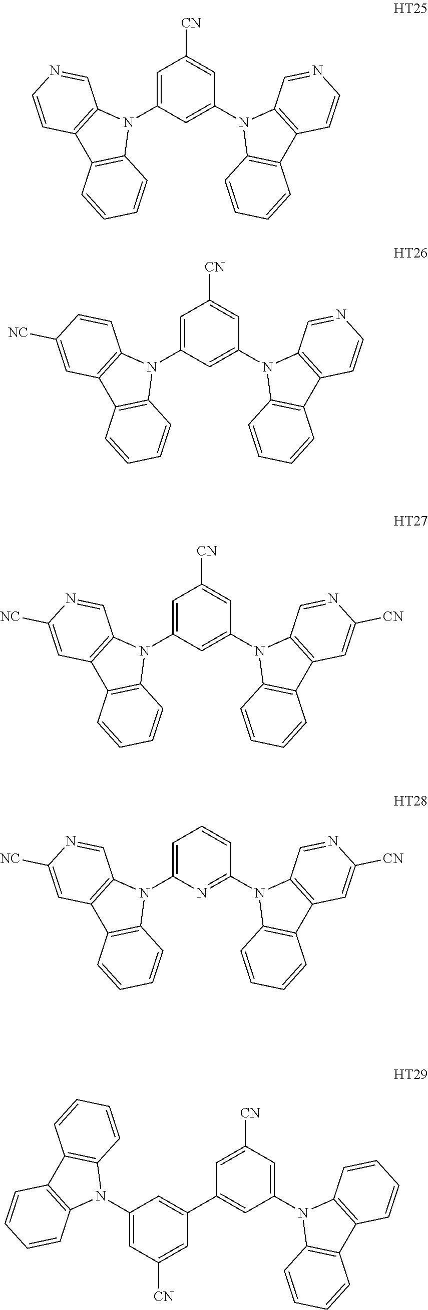 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

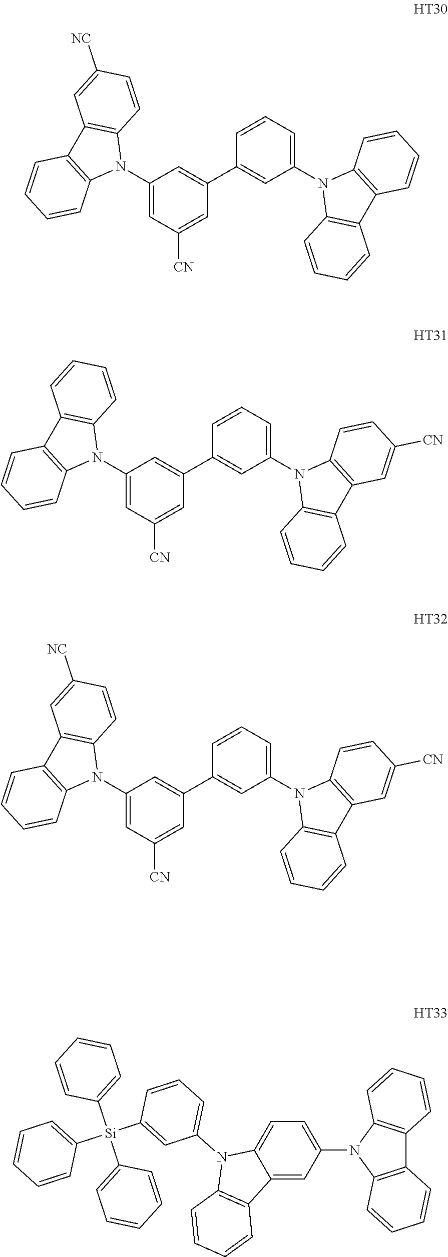 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

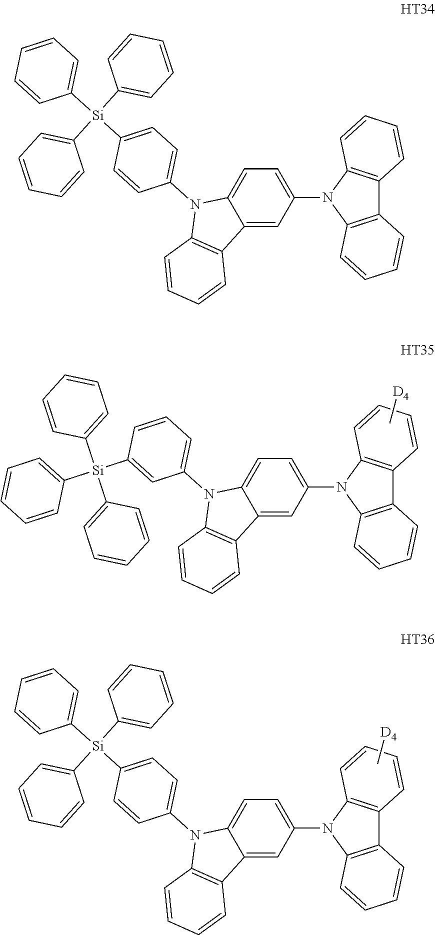

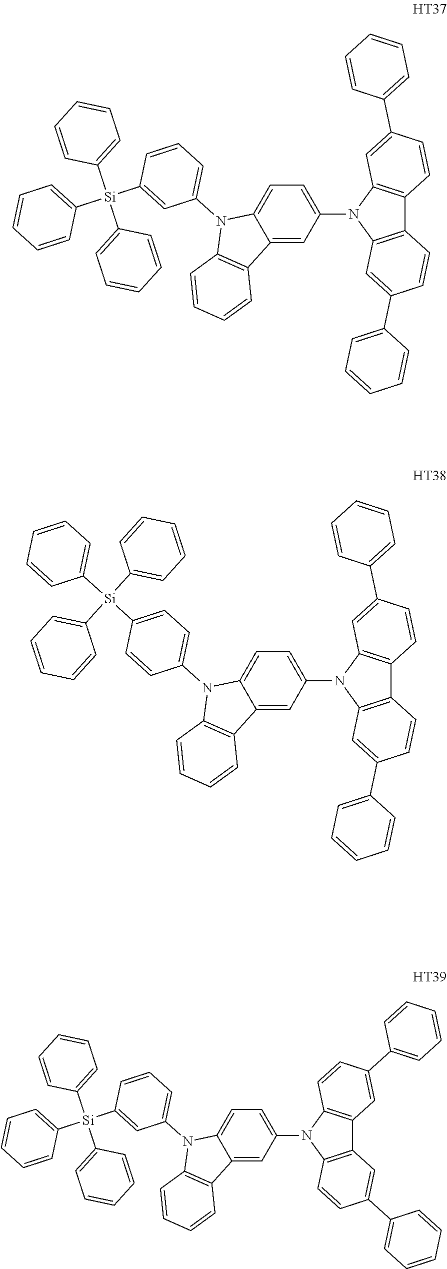 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

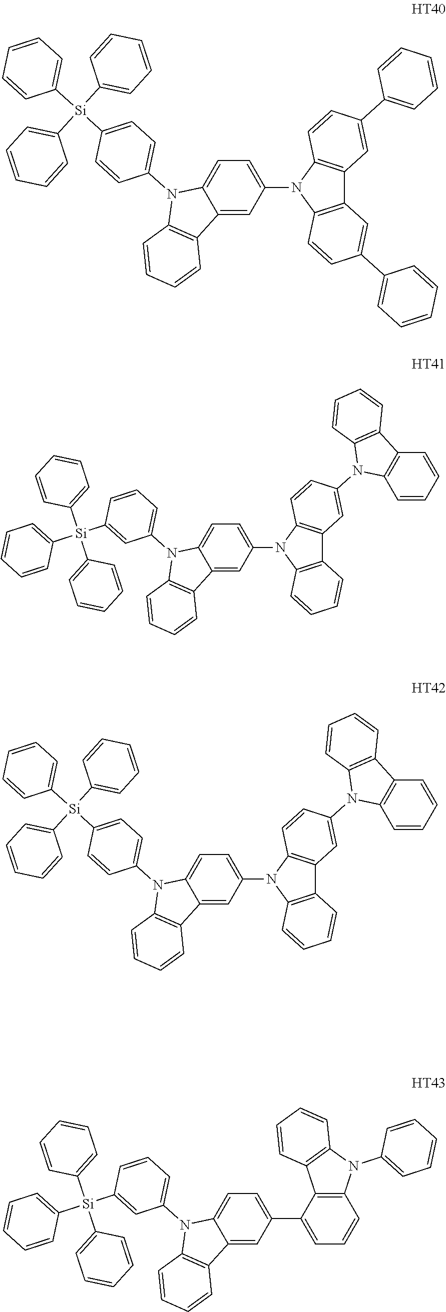 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

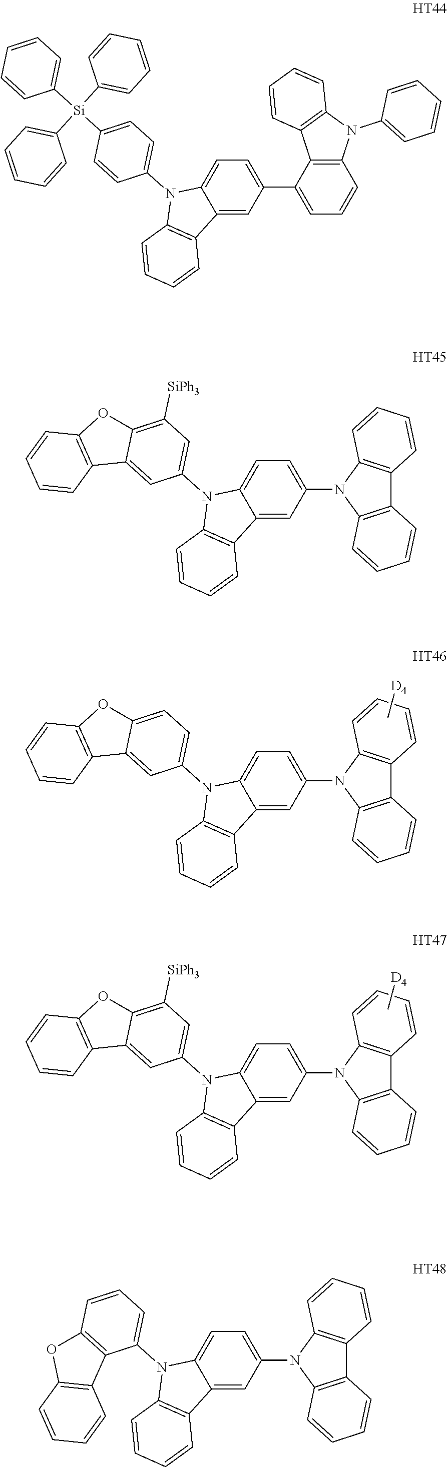

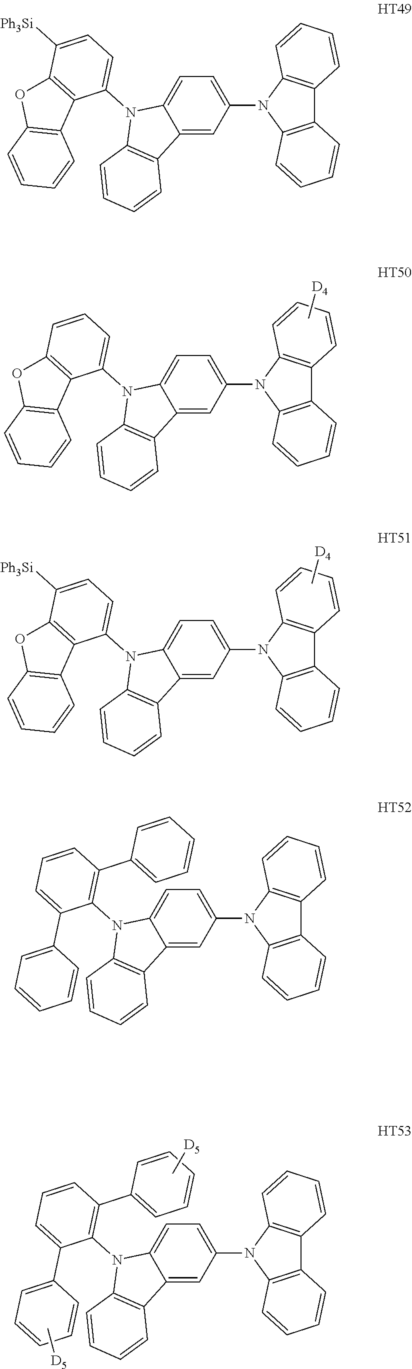

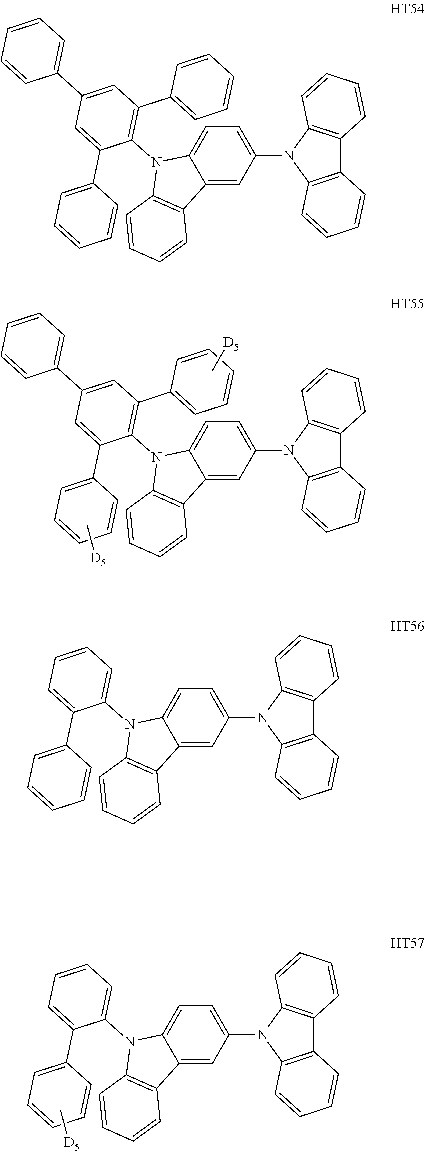

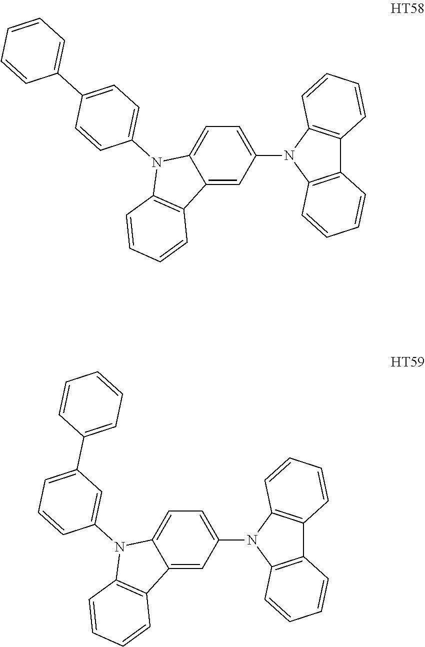 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may refer to deuterium, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transporting host material for the emission layer EML.

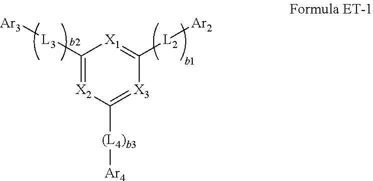

In Formula ET-1, at least one selected from among X₁ to X₃ may be N, and the rest are CR₅₆. For example, in one or more embodiments, one selected from among X₁ to X₃ may be N, and the rest may each independently be CR₅₆. In these embodiments, the third compound represented by Formula ET-1 may include a pyridine moiety. In one or more embodiments, two selected from among X₁ to X₃ may be N, and the rest may be CR₅₆. In these embodiments, the third compound represented by Formula ET-1 may include a pyrimidine moiety. In one or more embodiments, X₁ to X₃ may all be N. In these embodiments, the third compound represented by Formula ET-1 may include a triazine moiety.

In Formula ET-1, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are each an integer of 2 or greater, L₂ to L₄ each in plurality may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include at least one selected from among the compounds in Compound Group 3.

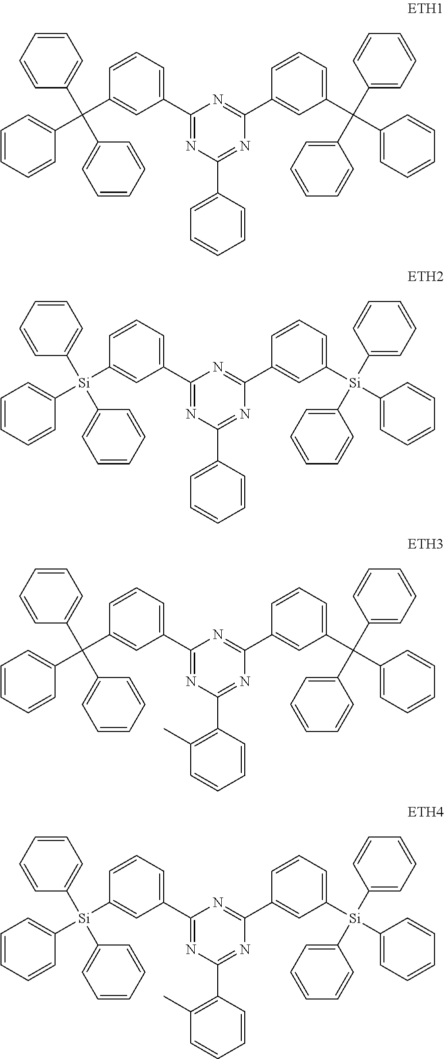 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

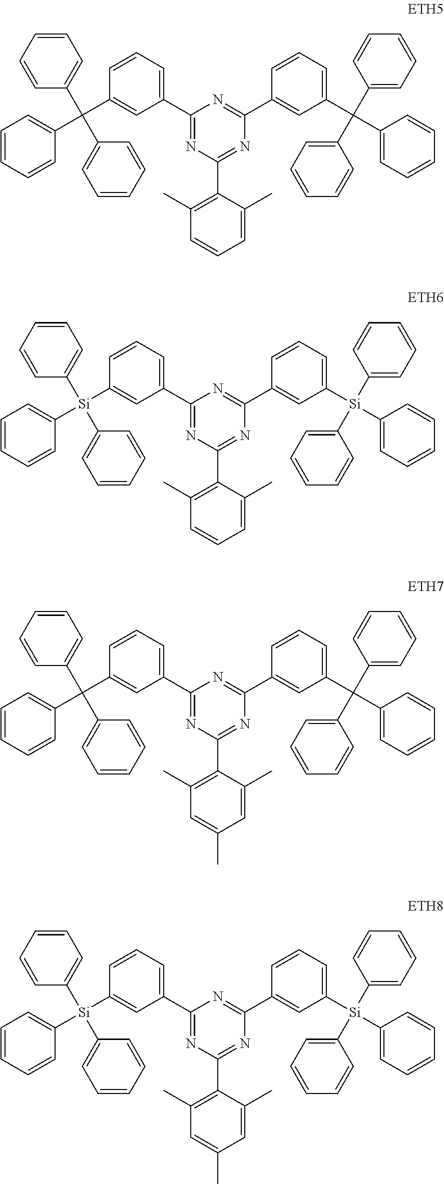 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

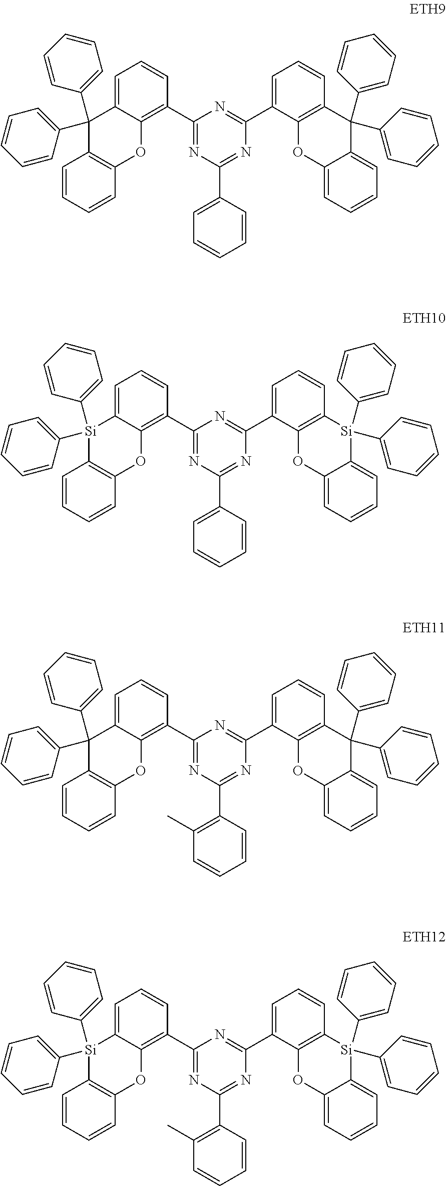 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

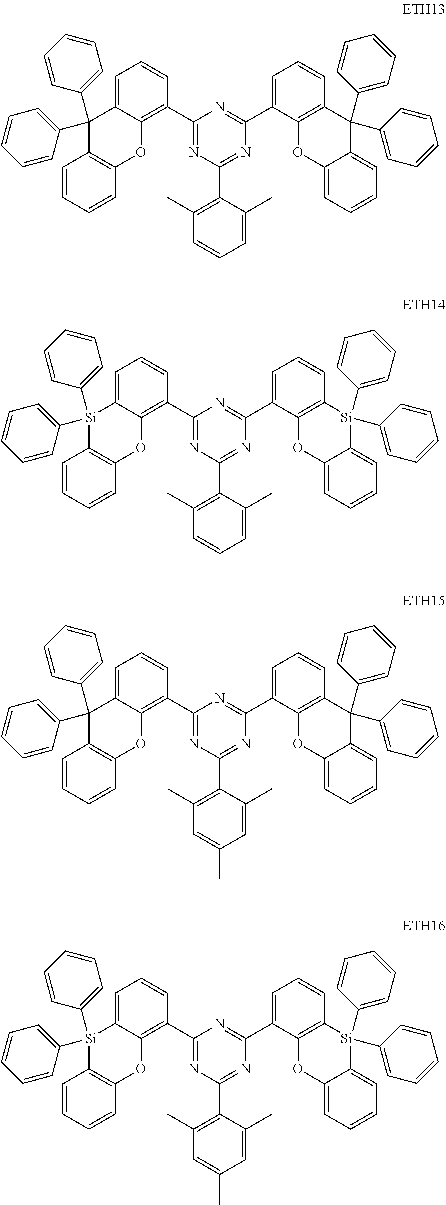 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

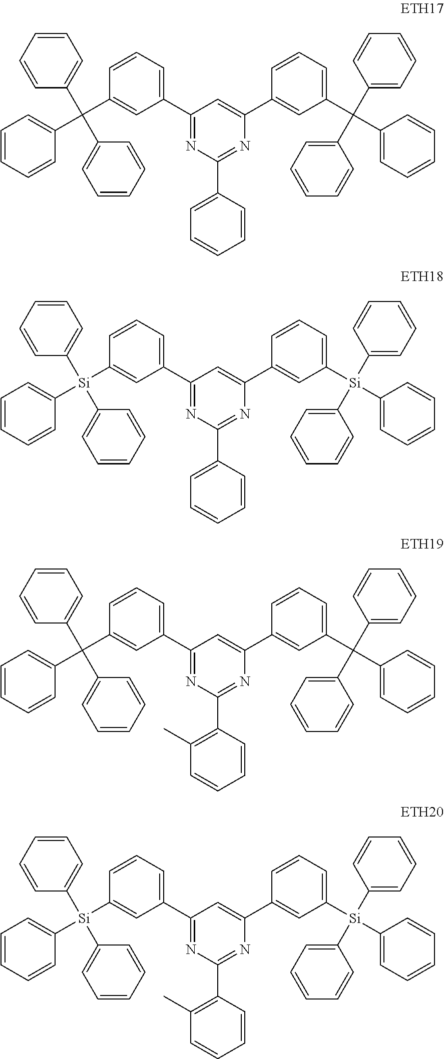 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

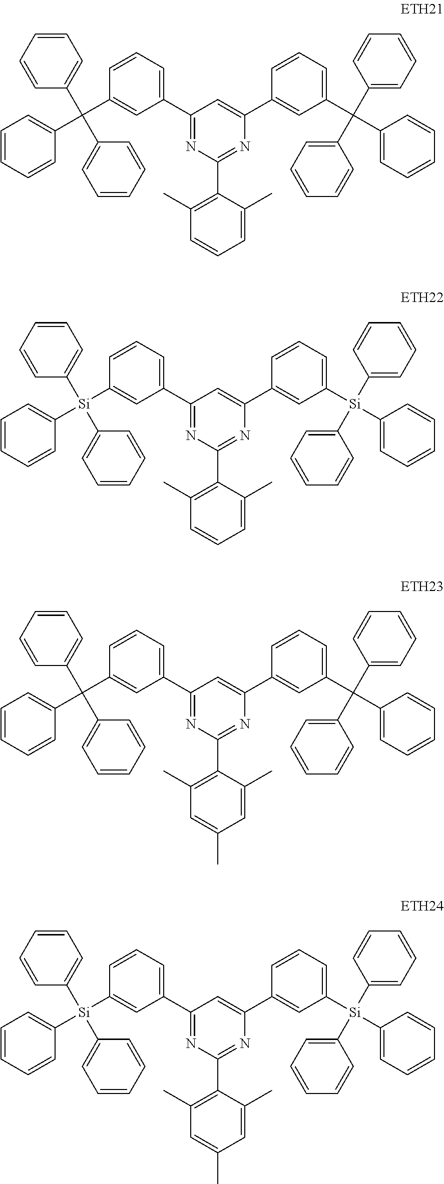 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

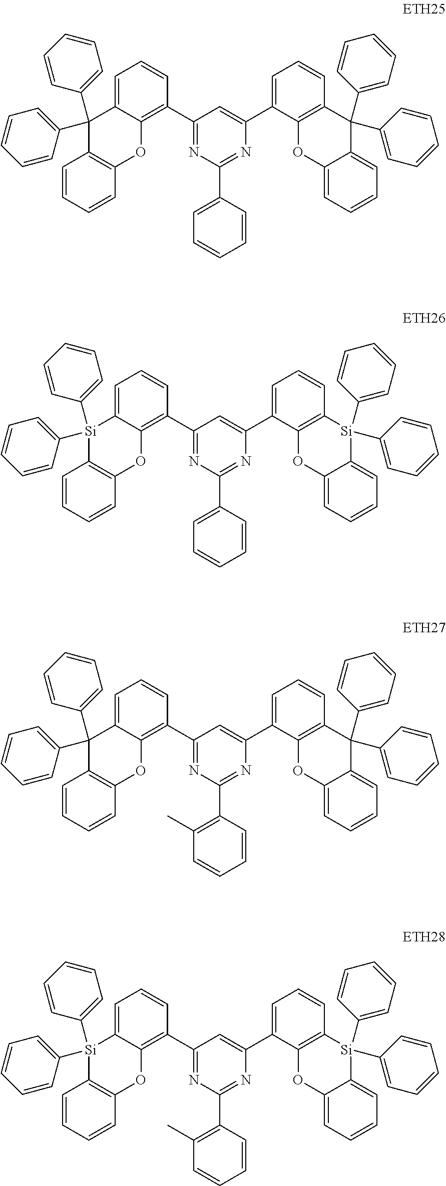 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

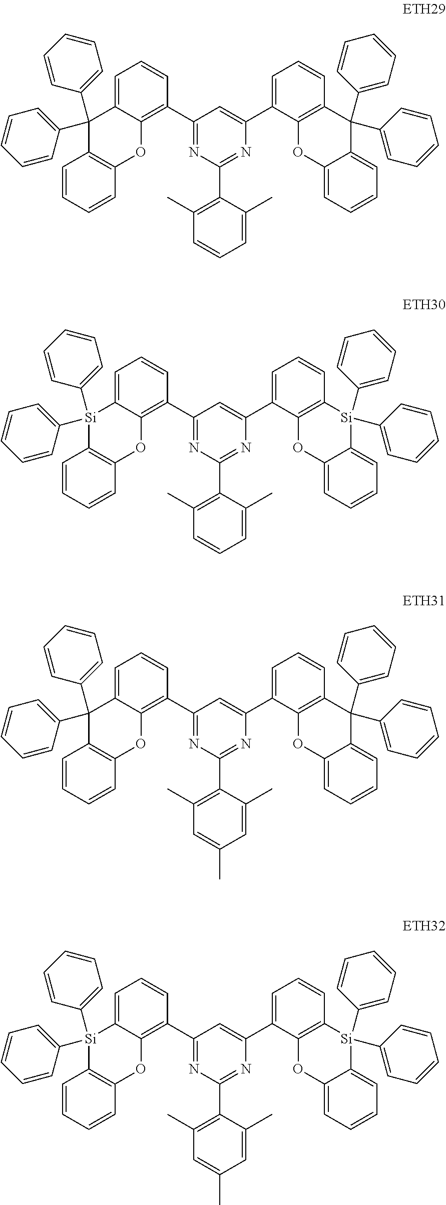 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

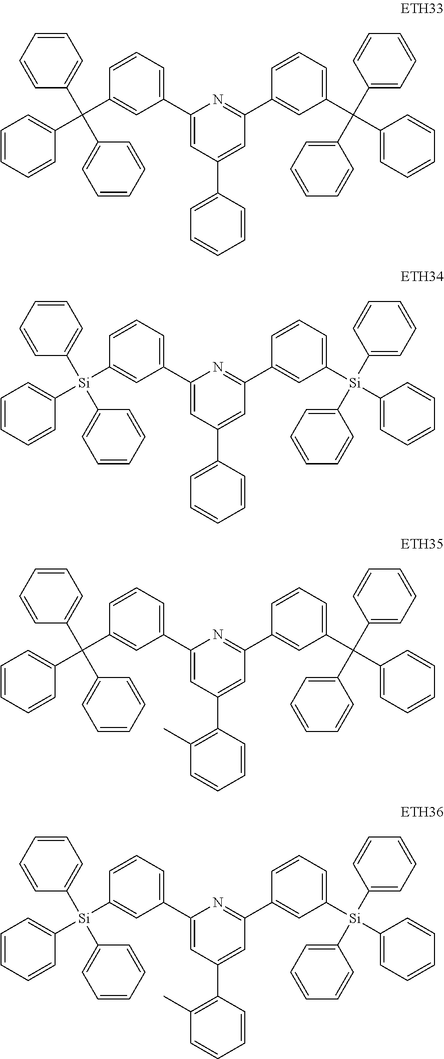 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

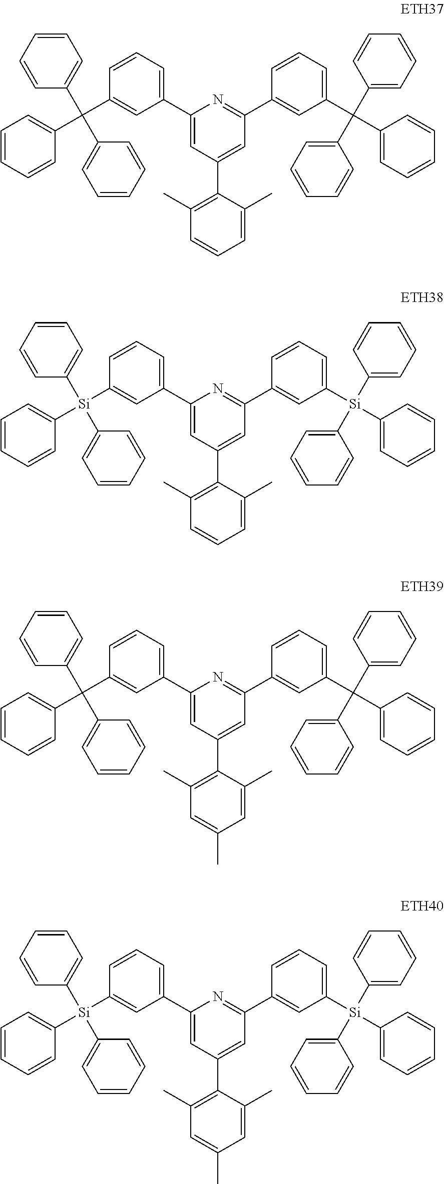 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

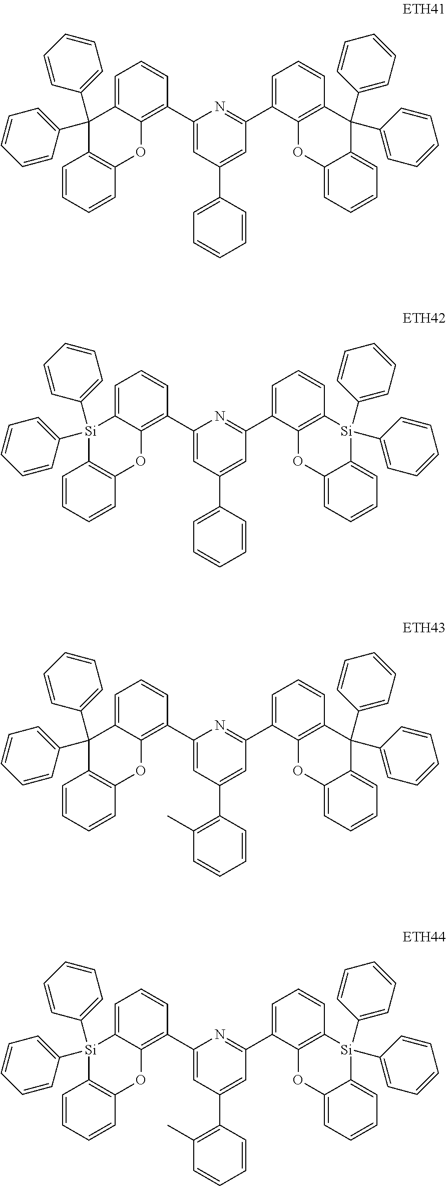 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

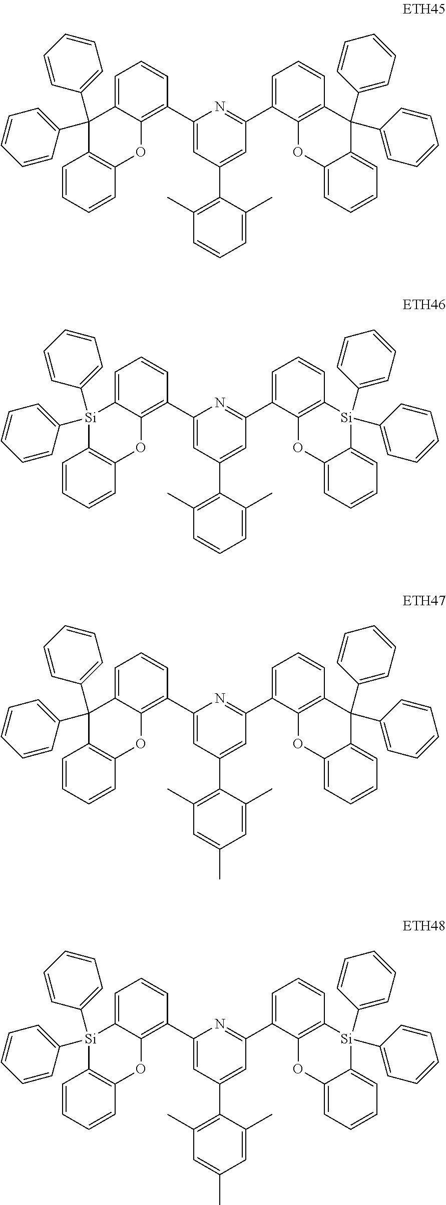 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

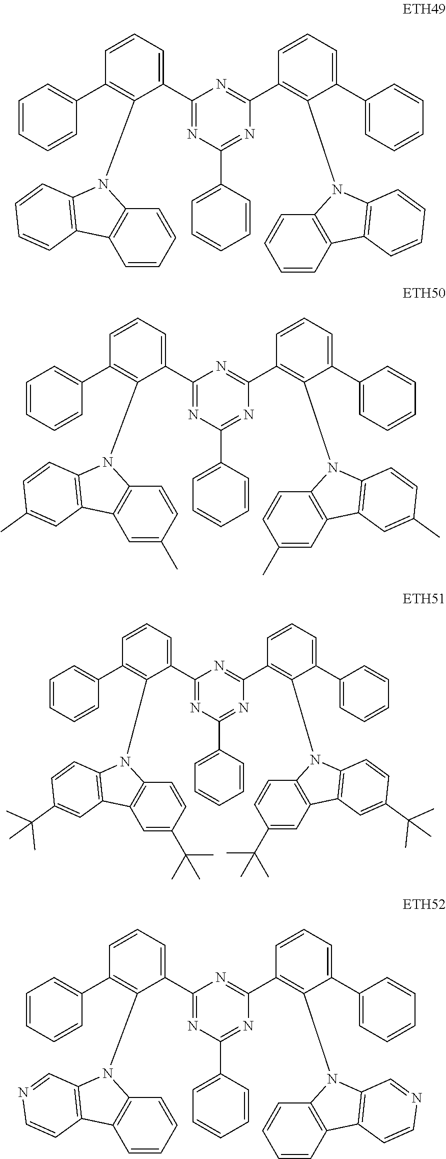

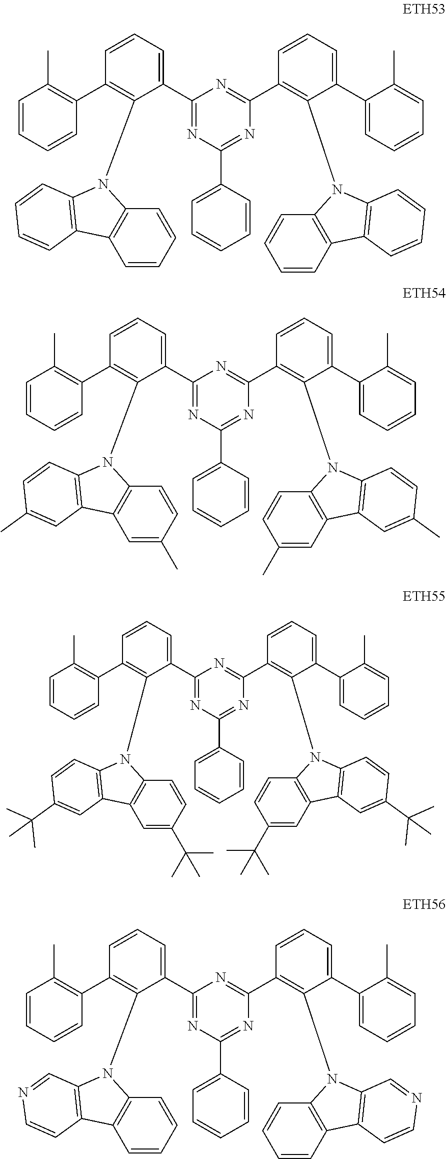

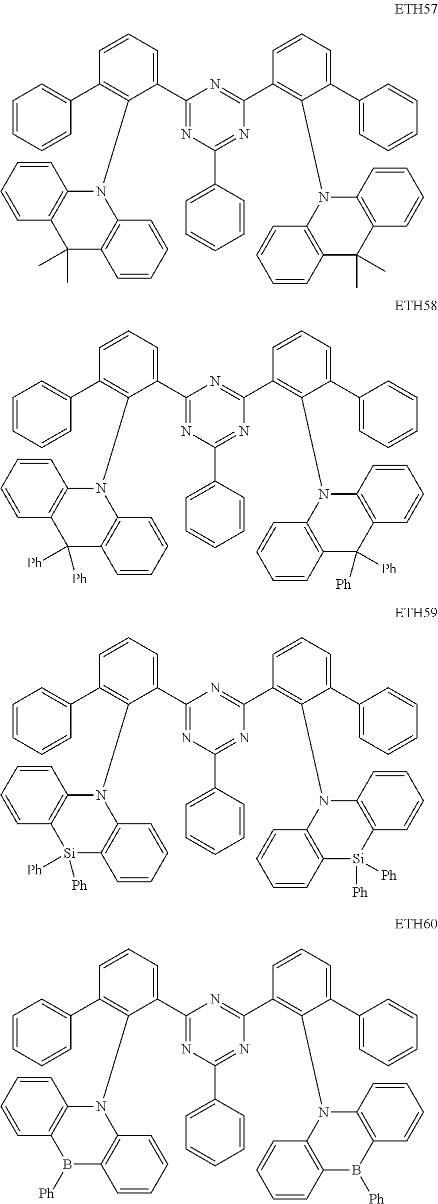

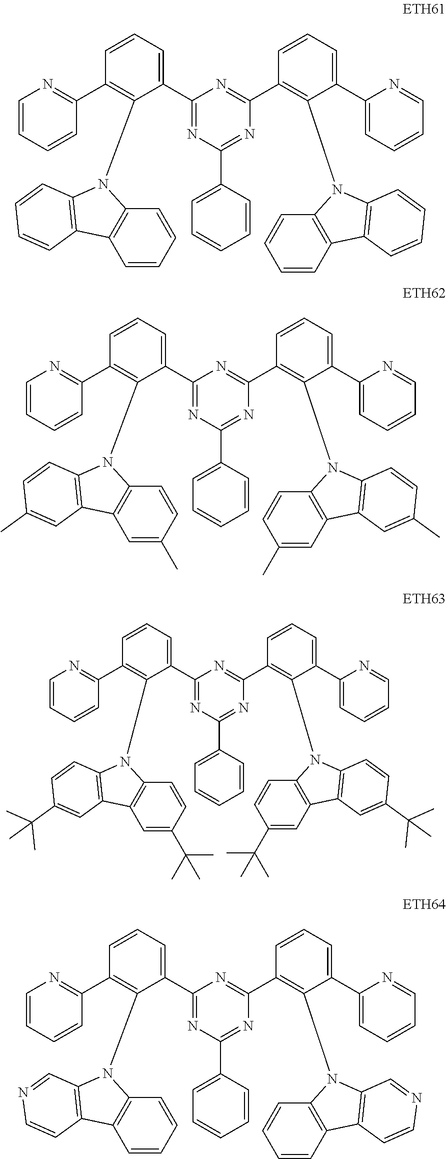

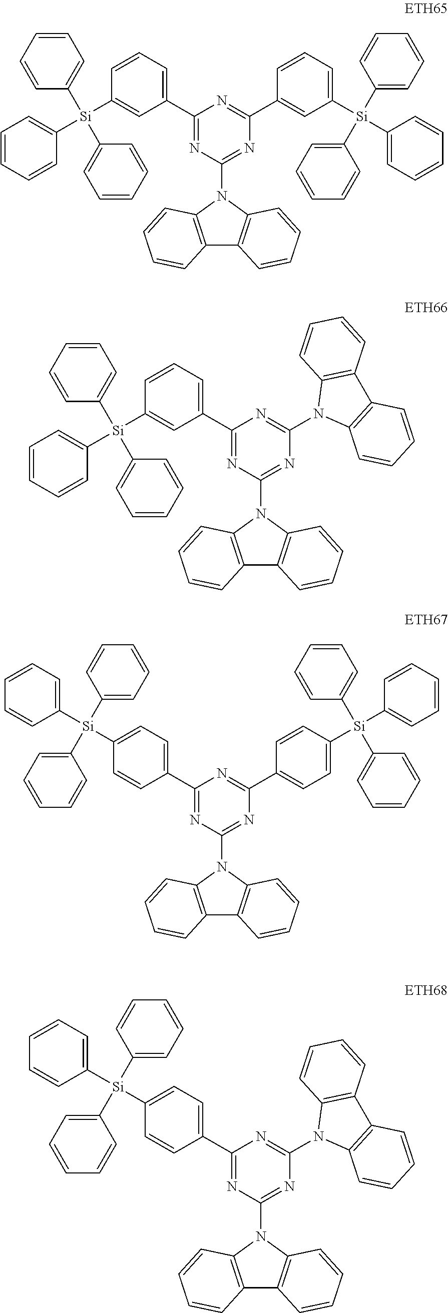 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

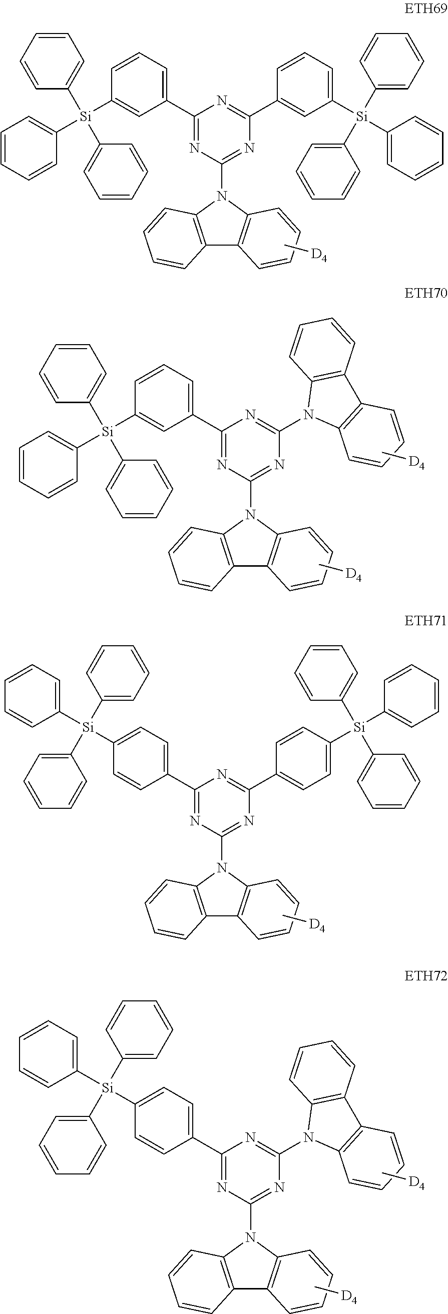

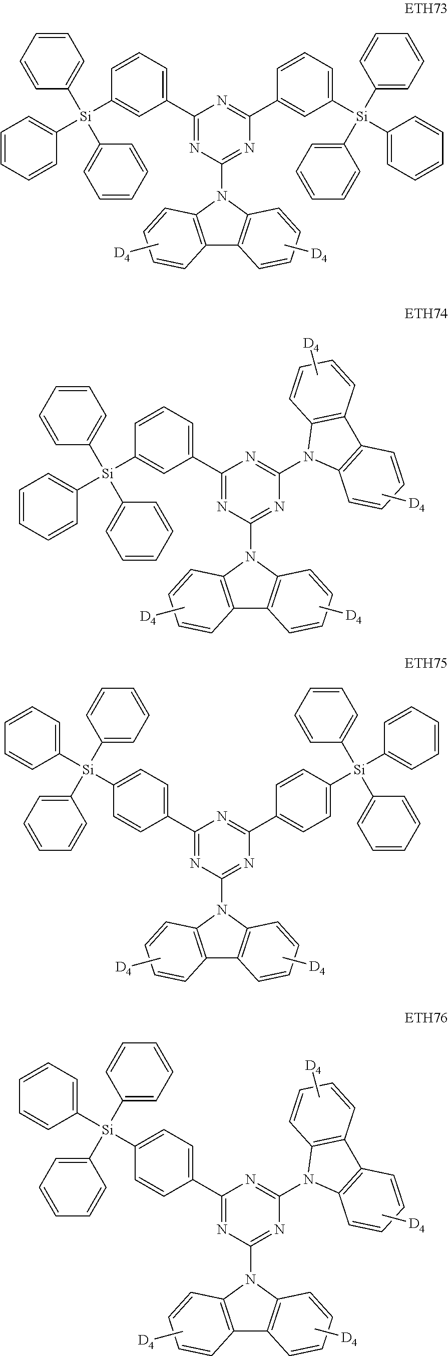

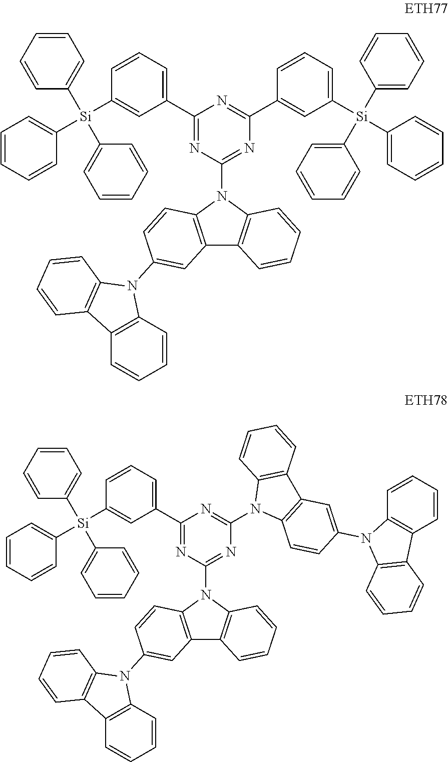 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

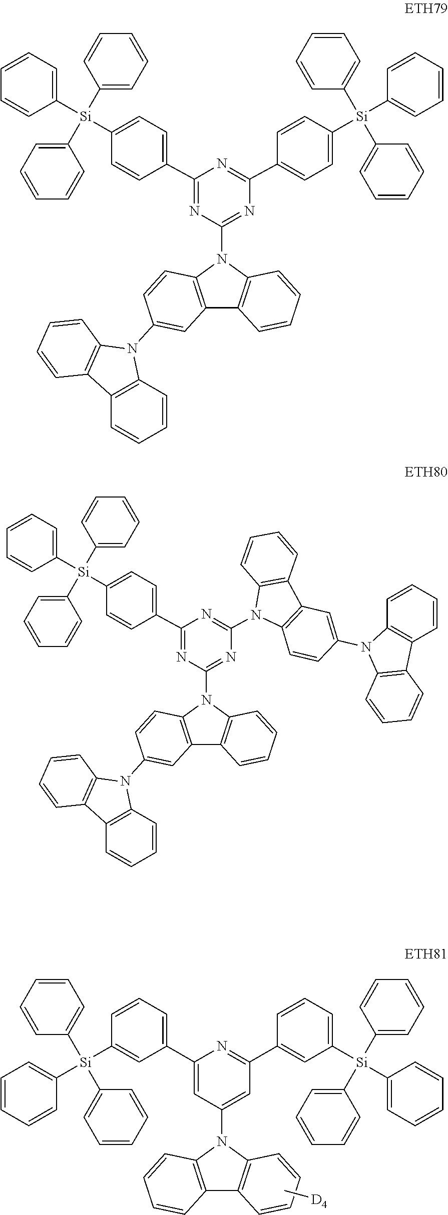

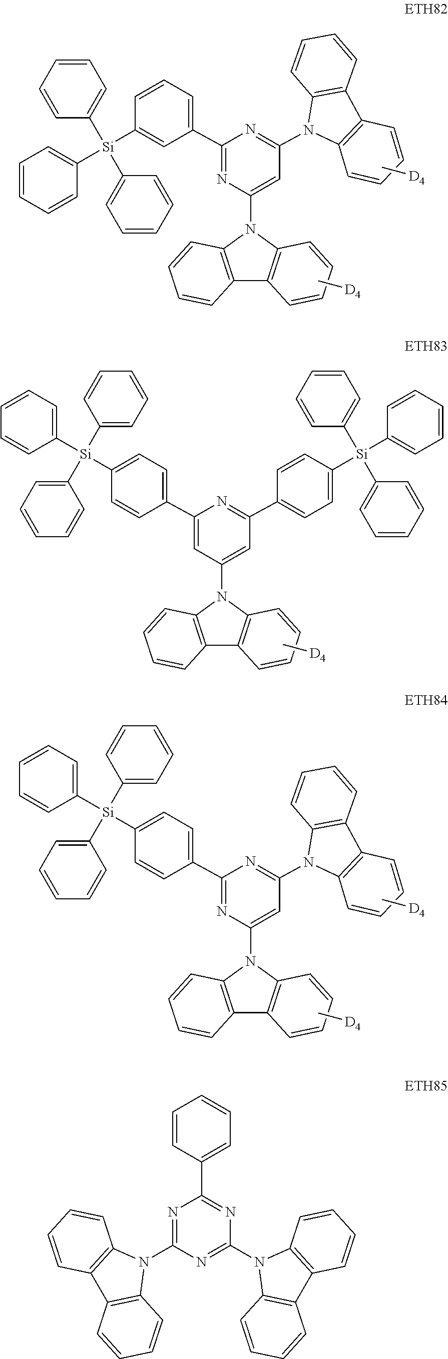

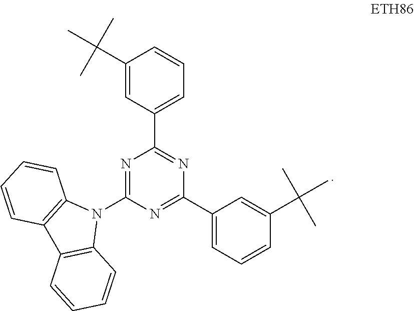 [SMILES: CC(C)(C)c1cccc(-c2nc(-c3cccc(C(C)(C)C)c3)nc(-n3c4ccccc4c4ccccc43)n2)c1]

In the embodiment compounds presented in Compound Group 3, “D” refers to deuterium and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. In this regard, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, in one or more embodiments, the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described above. The fourth compound may be used as a phosphorescent sensitizer of the emission layer EML. Energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

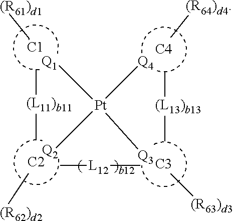

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

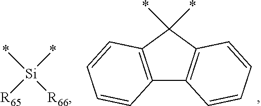

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*” refers to a part linked to one of C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may each independently be bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with R₆₁ to R₆₄. The embodiment in which each of d1 to d4 is 4 and R₆₁'s to R₆₄′ are each hydrogen may be the same as the embodiment in which each of d1 to d4 is 0. If (e.g., when) each of d1 to d4 is an integer of 2 or more, a plurality of R₆₁'s to R₆₄'s may each be the same, or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

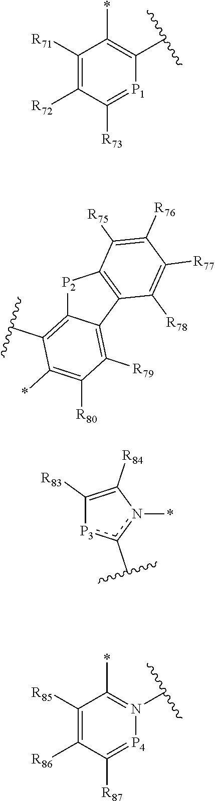

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may each independently be bonded to an adjacent group to form a ring.

In addition, in C-1 to C-4,

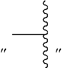

corresponds to a part linked to Pt that is a central metal atom, and “—*” corresponds to a part linked to a neighboring cyclic group (C1 to C4) or a neighboring linker (L₁₁ to L₁₃).

The emission layer EML of one or more embodiments may include the first compound, which is the fused polycyclic compound of one or more embodiments, and at least one selected from among the second to fourth compounds. For example, in one or more embodiments, the emission layer EML may include the first compound, the second compound, and the third compound. In the emission layer EML, the second compound and the third compound may form an exciplex, and energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In addition, if (e.g., when) the energy delivery to the first compound is increased, an exciton formed in the emission layer EML is not accumulated inside the emission layer EML and emits light rapidly, and thus deterioration of the light emitting element may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be any one among selected from compounds represented by Compound Group 4. The emission layer EML may include at least one selected from among the compounds represented by Compound Group 4 as a sensitizer material.

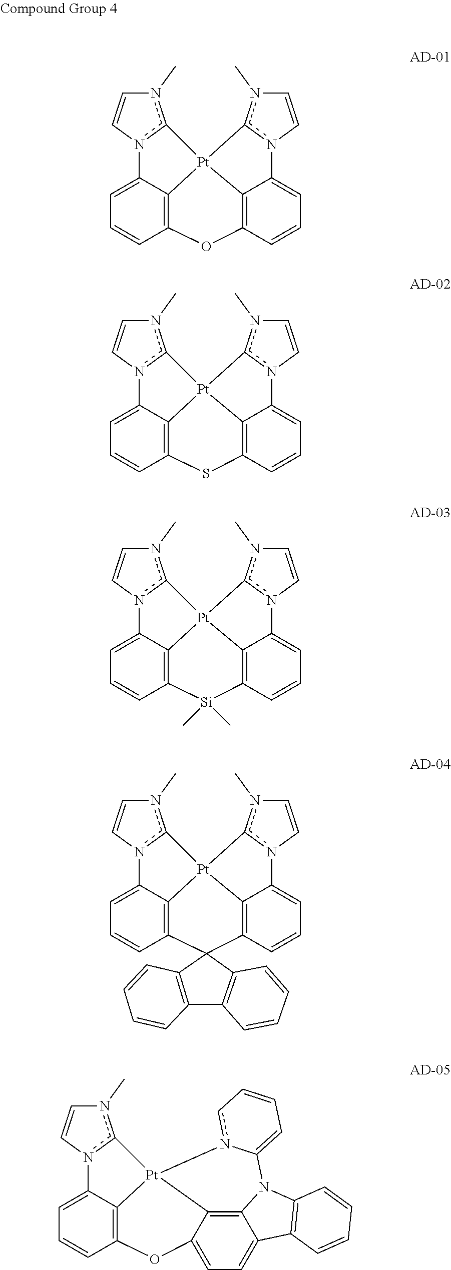

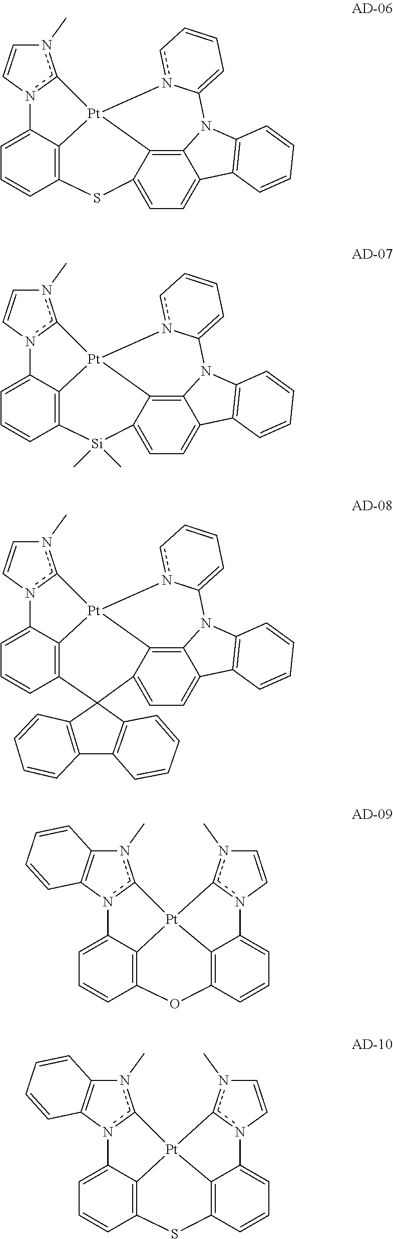

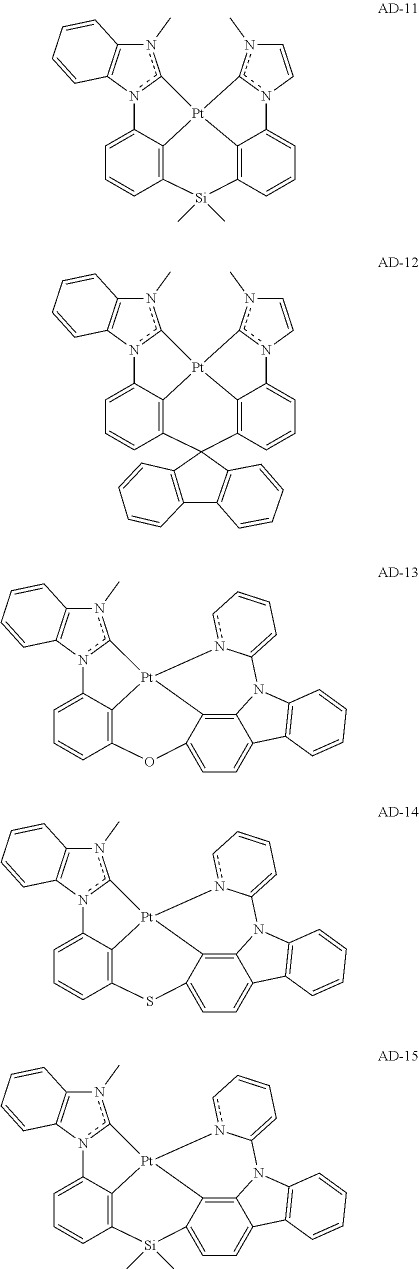

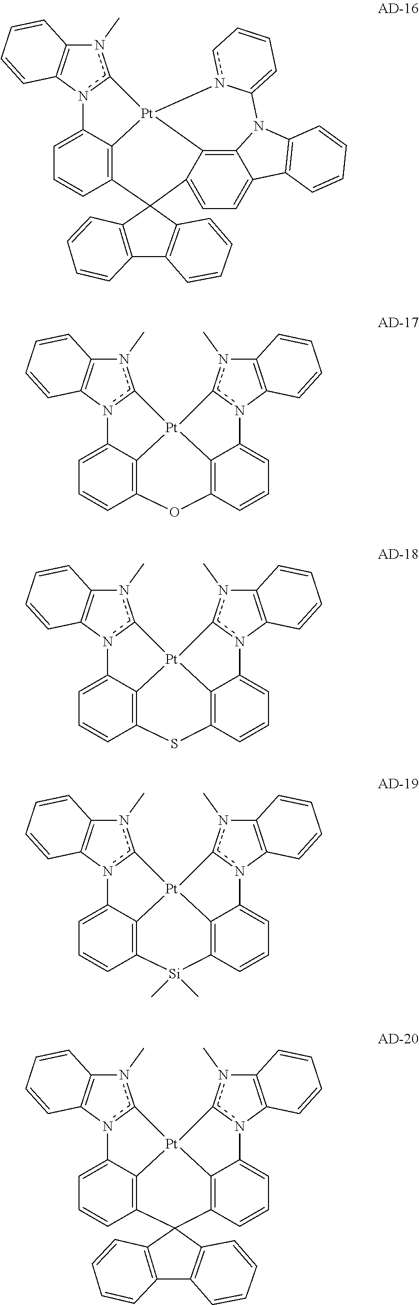

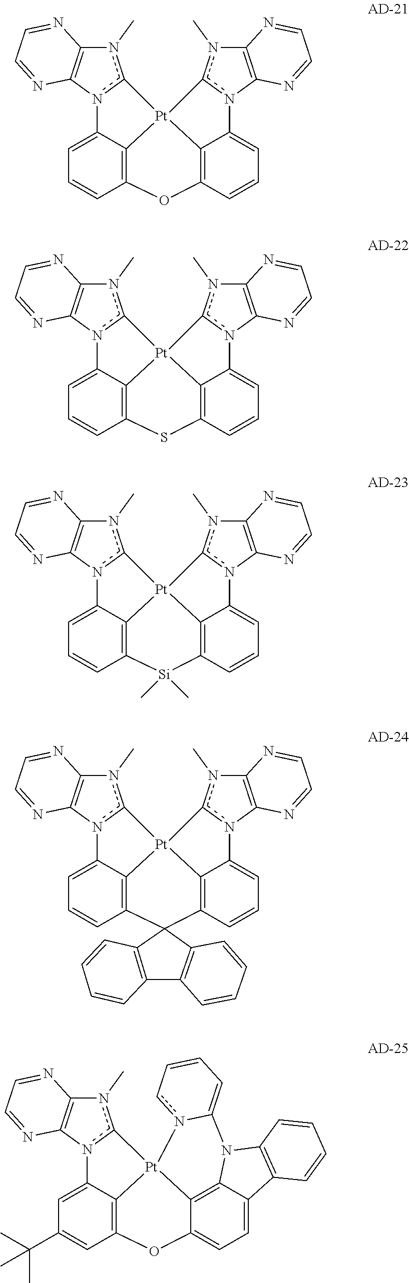

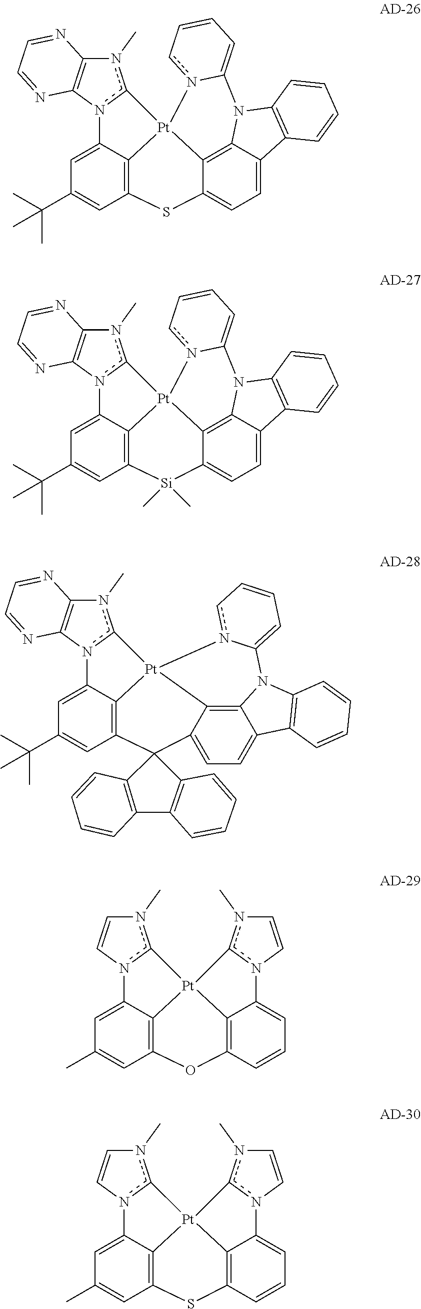

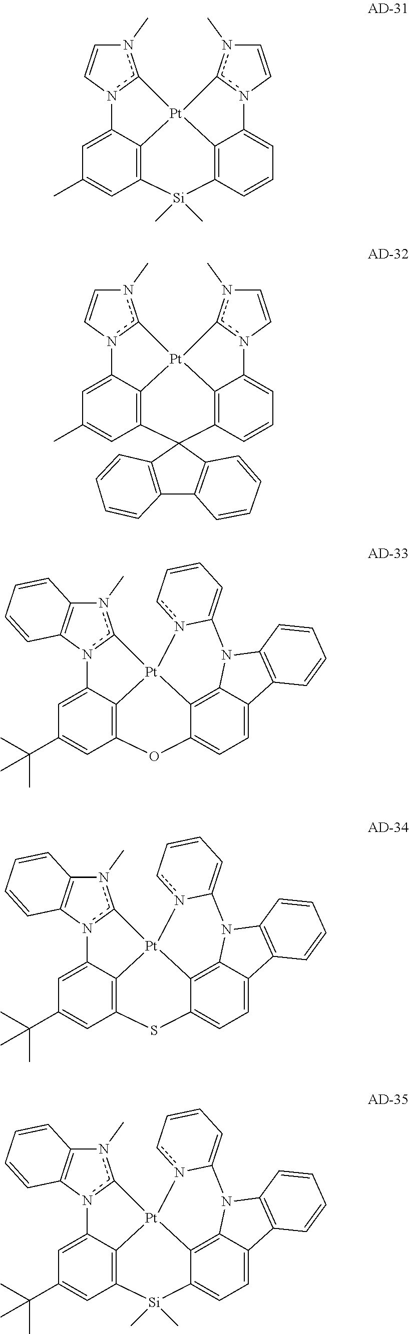

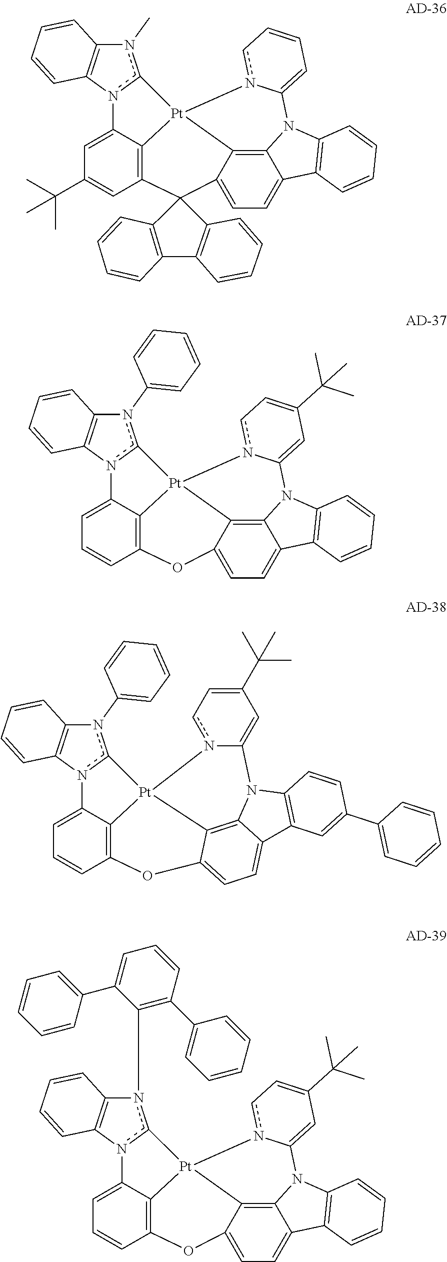

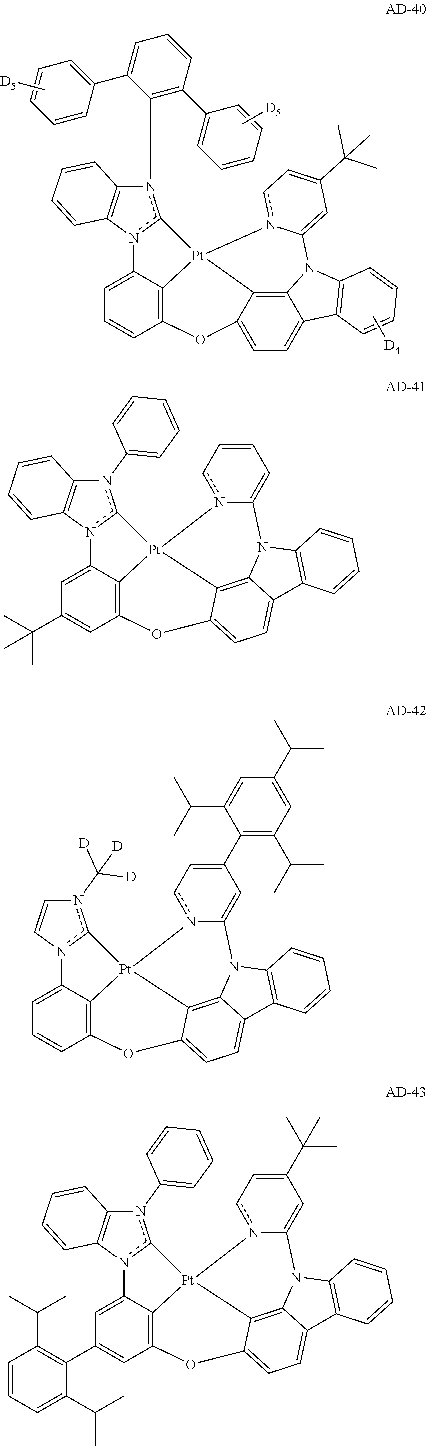

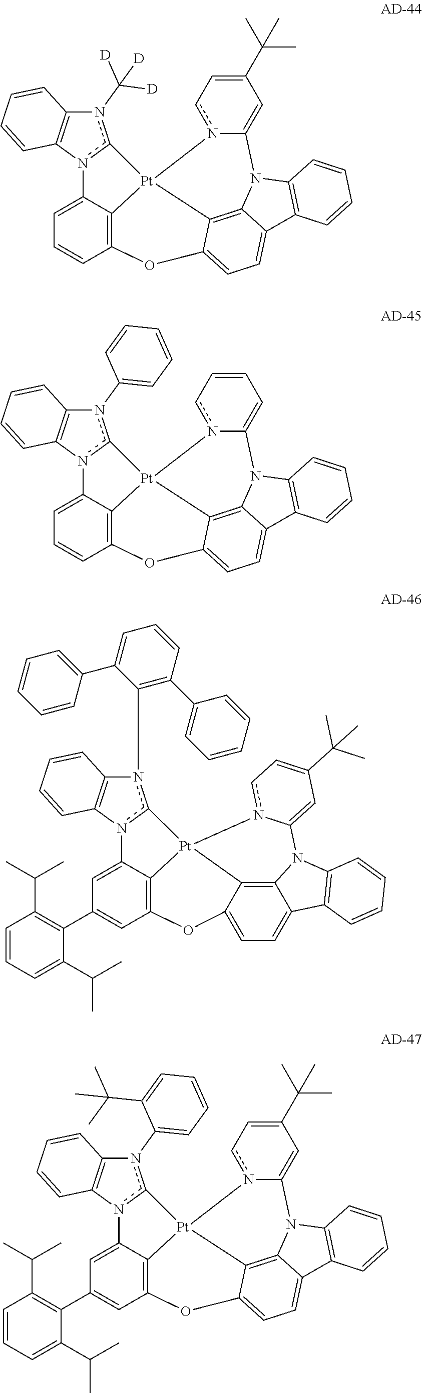

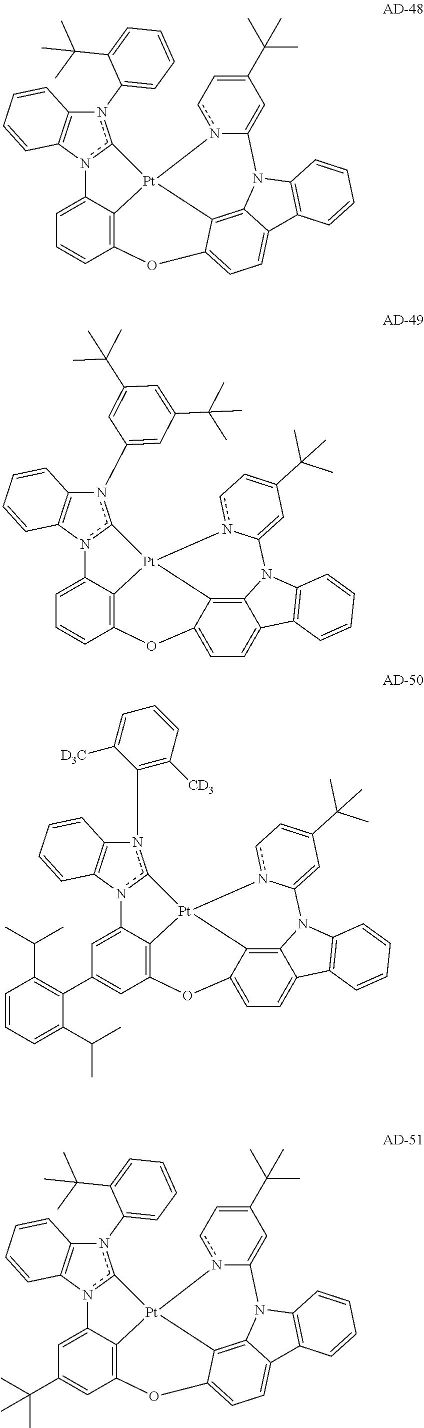

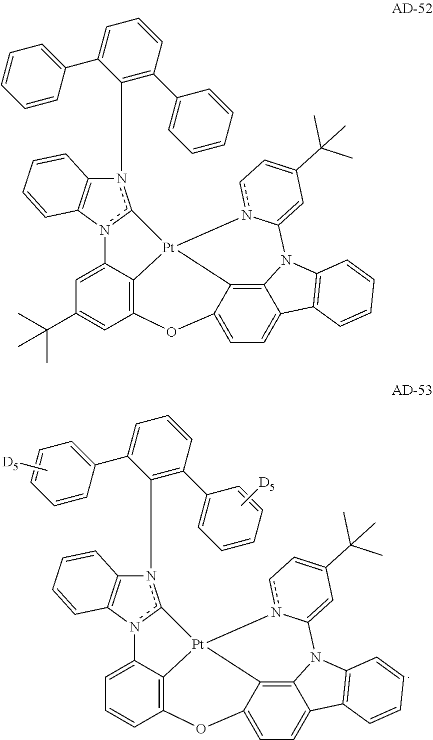

In the embodiment compounds presented in Compound Group 4, “D” refers to deuterium.

If (e.g., when) the emission layer EML in the light emitting element ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, embodiments of the present disclosure are not limited thereto. If (e.g., when) the content (e.g., amount) of the first compound satisfy the above-described proportion, energy transfer from the second compound and the third compound to the first compound may increase, and thus the luminous efficiency and element service life may increase.

The contents (e.g., amounts) of the second compound and the third compound in the emission layer EML may be the rest excluding the weight of the first compound. For example, the contents (e.g., amounts) of the second compound and the third compound in the emission layer EML may be about 65 wt % to about 95 wt % with respect to the total weight of the first compound, the second compound, and the third compound.

In the total weight of the second compound and the third compound, a weight ratio of the second compound to the third compound may be about 3:7 to about 7:3.

When the contents (e.g., amounts) of the second compound and the third compound satisfy the above-described ratio, a charge balance characteristic in the emission layer EML are improved, and thus the luminous efficiency and element service life may increase. When the contents of the second compound and the third compound deviate from the above-described ratio range, a charge balance in the emission layer EML is broken, and thus the luminous efficiency may be reduced, and the element may be easily deteriorated.

In one or more embodiments, when the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, embodiments of the present disclosure are not limited thereto. When the content (e.g., amount) of the fourth compound satisfies the above-described content (e.g., amount) range, energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In one or more embodiments, the emission layer EML may further include a compound described below in addition to the fused polycyclic compound of one or more embodiments.

In the light emitting element ED of one or more embodiments, the emission layer EML may further include at least one of an anthracene derivative, a pyrene derivative, a fluoranthene derivative, a chrysene derivative, a dihydrobenzanthracene derivative, or a triphenylene derivative. For example, in one or more embodiments, the emission layer EML may include an anthracene derivative or a pyrene derivative.

In each light emitting element ED of embodiments illustrated in FIGS. 3 to 6, the emission layer EML may further include a suitable host and dopant besides the above-described host and dopant, and for example, in one or more embodiments, the emission layer EML may further include a compound represented by Formula E-1. The compound represented by Formula E-1 may be used as a fluorescent host material.

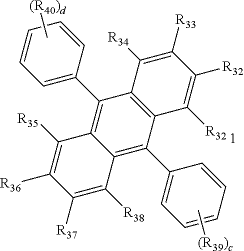

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may each independently be bonded to an adjacent group to form a ring. In one or more embodiments, one or more selected from among R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E21:

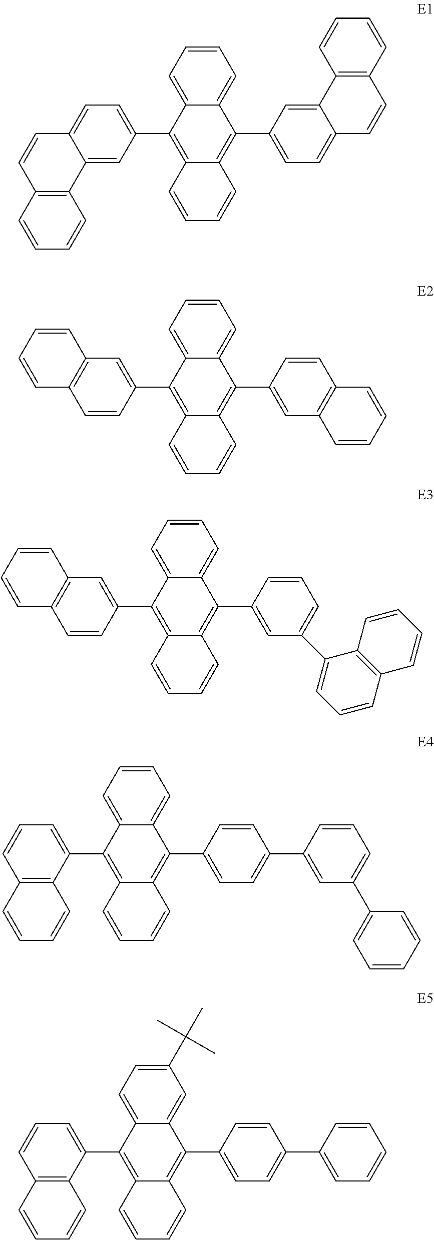

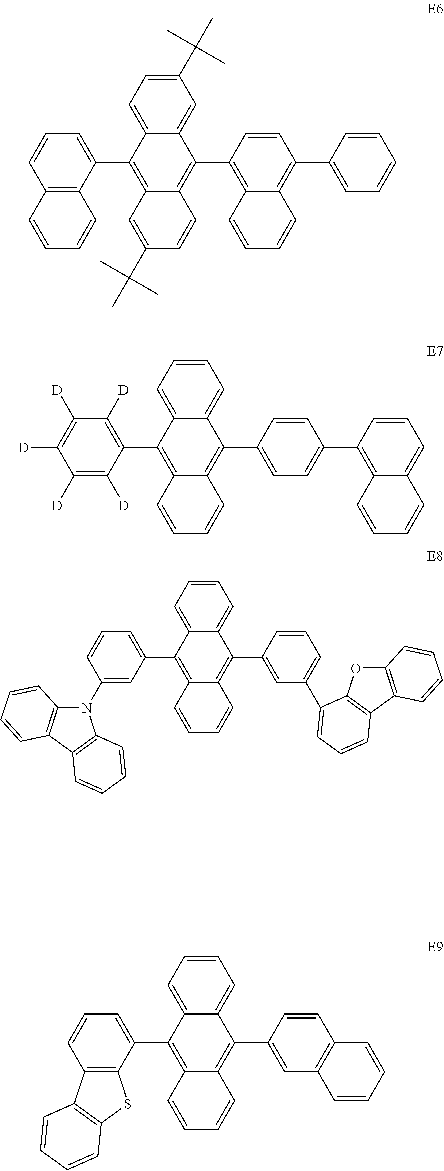

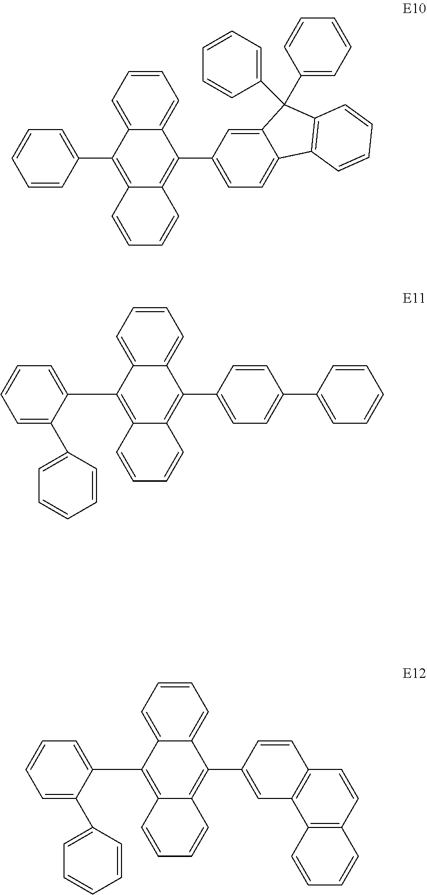

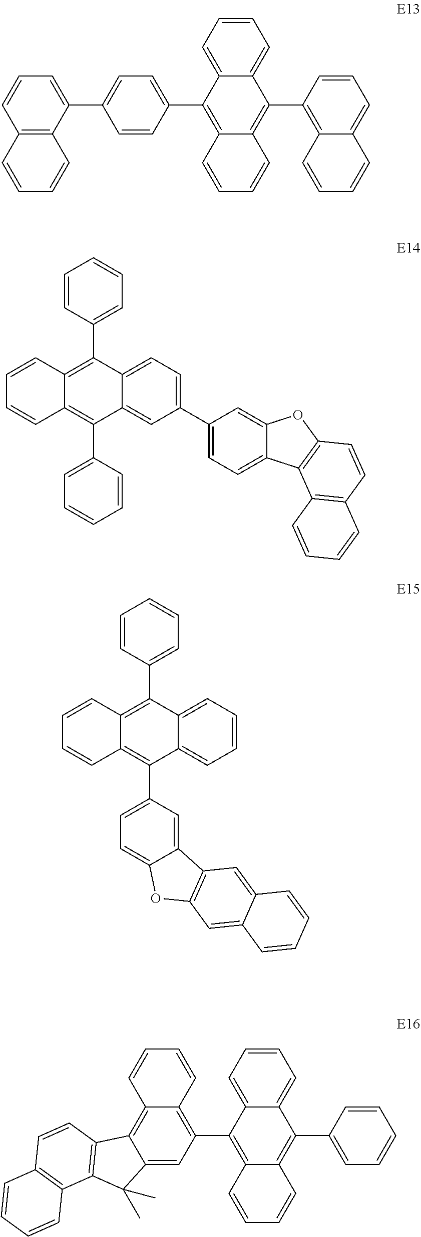

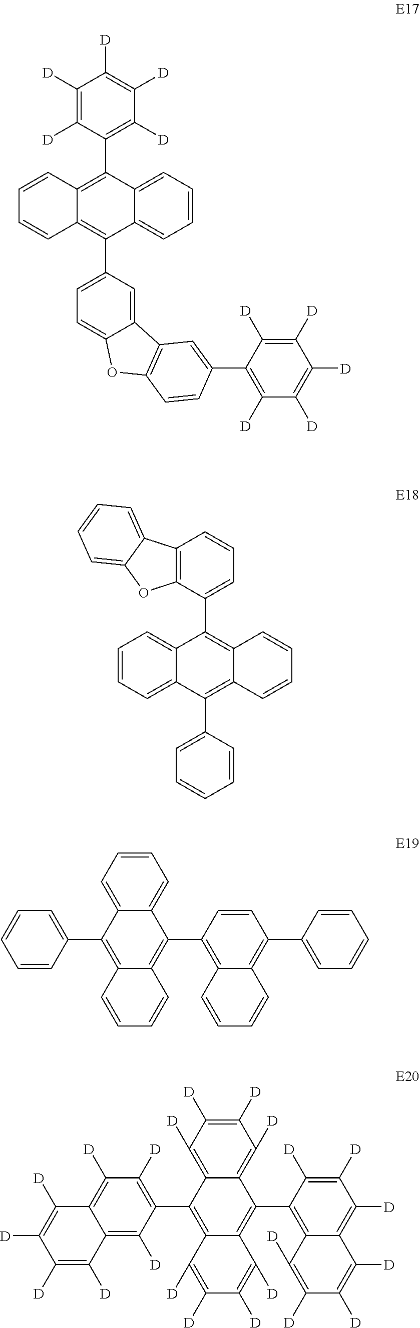

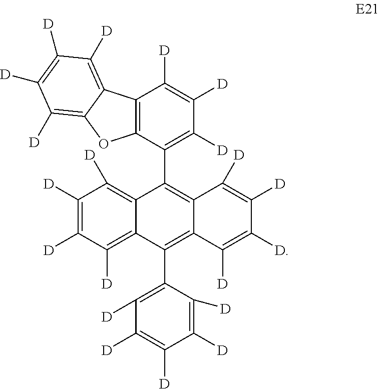

In one or more embodiments, the emission layer EML may further include a compound represented by Formula E-2a or Formula E-2b. The compound represented by Formula E-2a or Formula E-2b may be used as a host material in a phosphorescent emission layer.

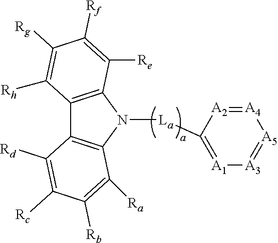

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of La's may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may independently be bonded to an adjacent group to form a ring. In one or more embodiments, one or more selected from among Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest are each CRᵢ.

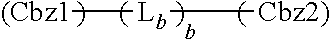

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. Meanwhile, b is an integer of 0 to 10, and if (e.g., when) b is an integer of 2 or more, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are merely examples, and the compound represented by Formula E-2a or Formula E-2b is not limited to those represented in Compound Group E-2.

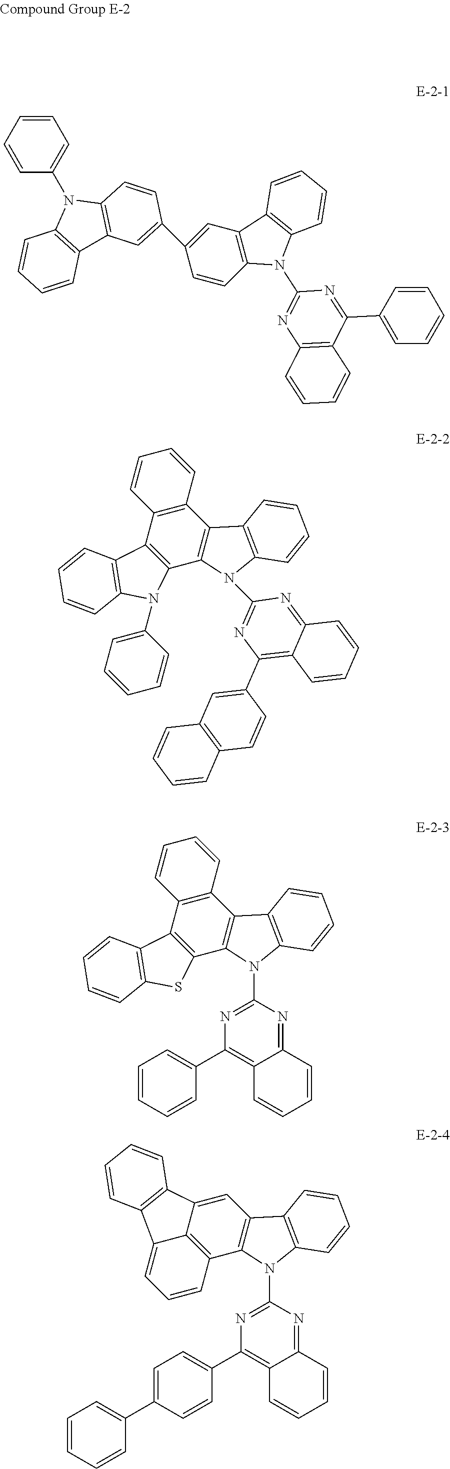

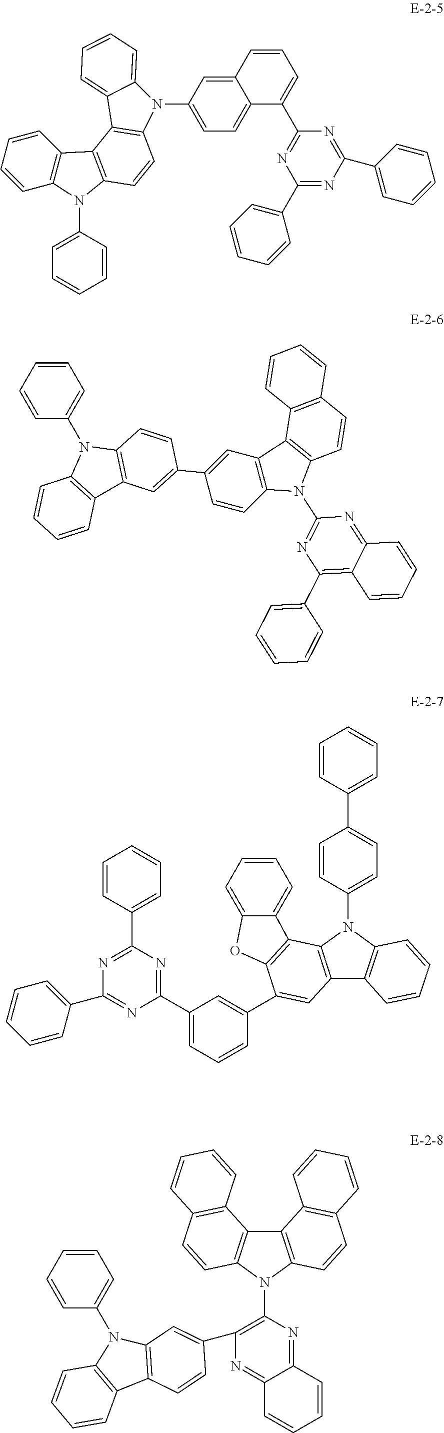 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

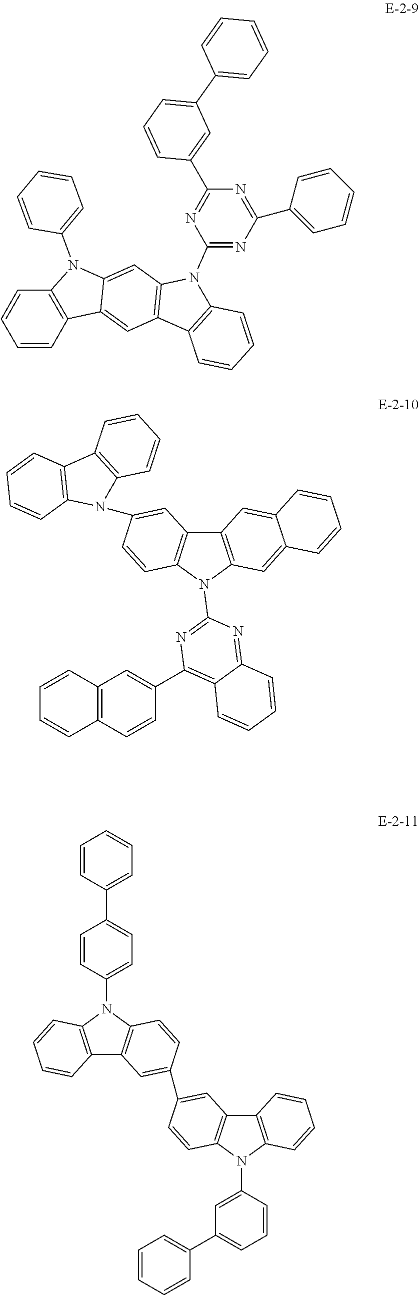 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

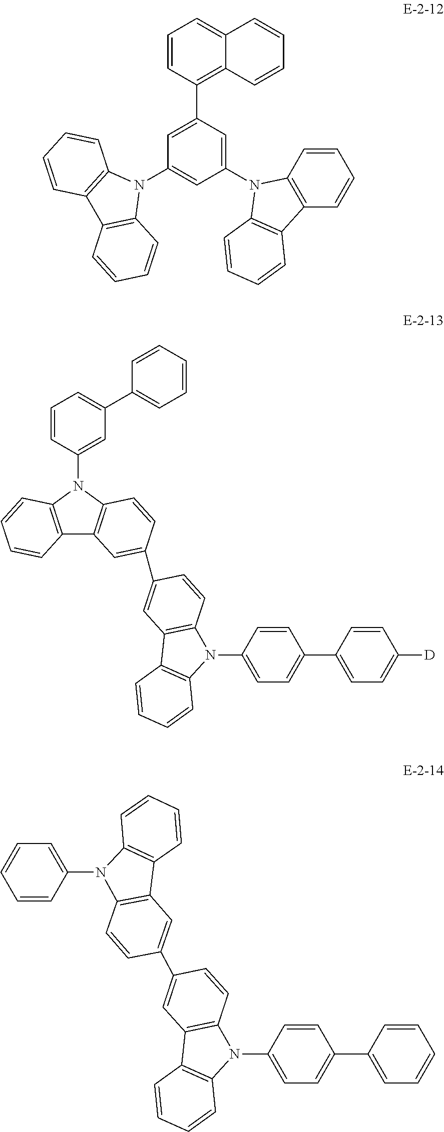 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1]

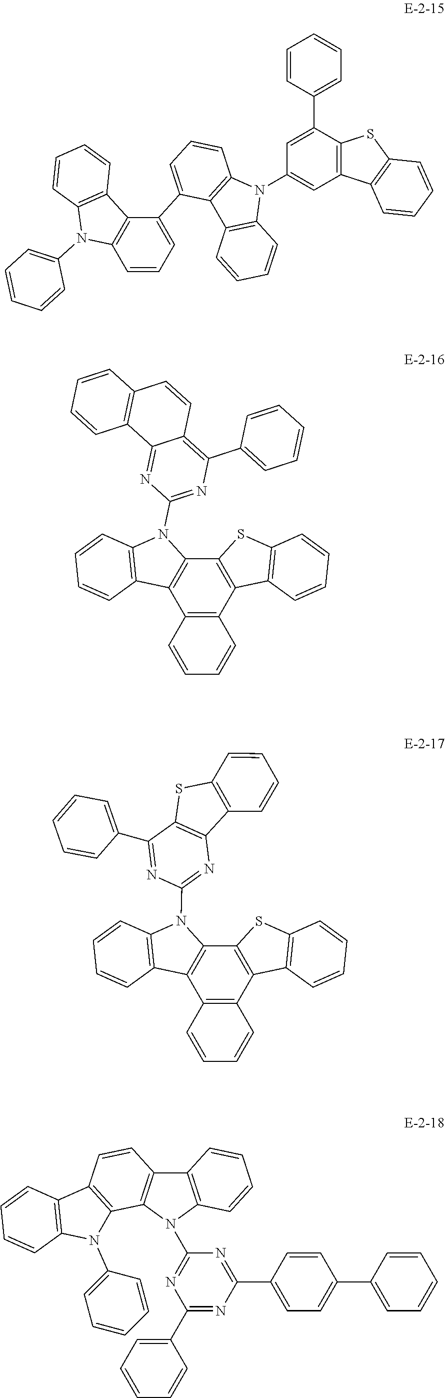 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

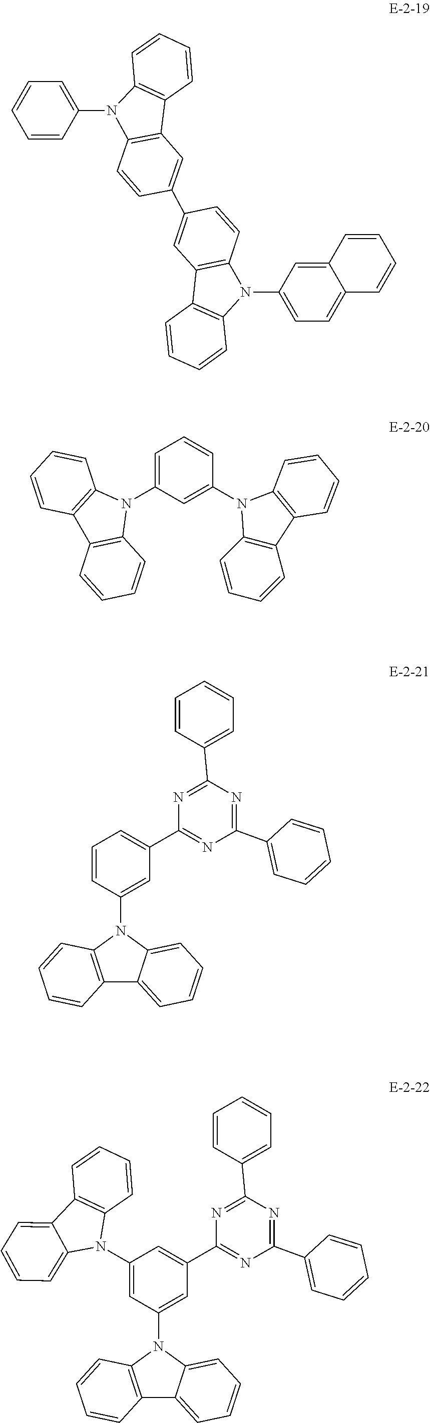 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

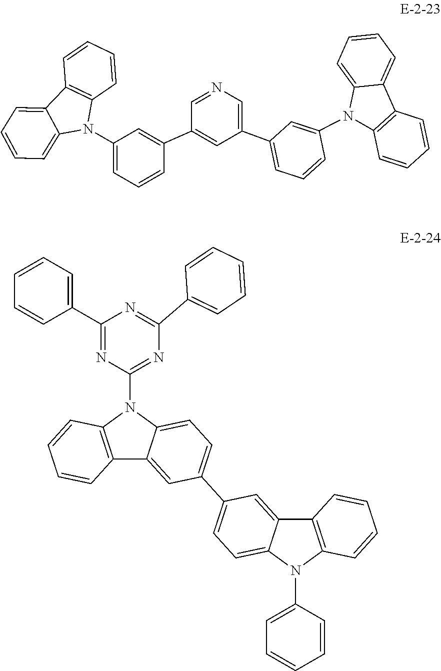 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, in one or more embodiments, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

In one or more embodiments, the emission layer EML may further include a compound represented by Formula M-a. The compound represented by Formula M-a may be used as a phosphorescent dopant material.

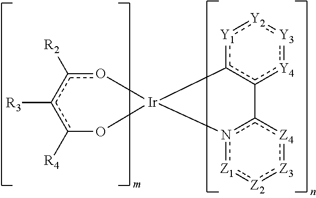

In Formula M-a, Y₁ to Y₄ and Z₁ to Z₄ may each independently be CR₁ or N, Rᵢ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

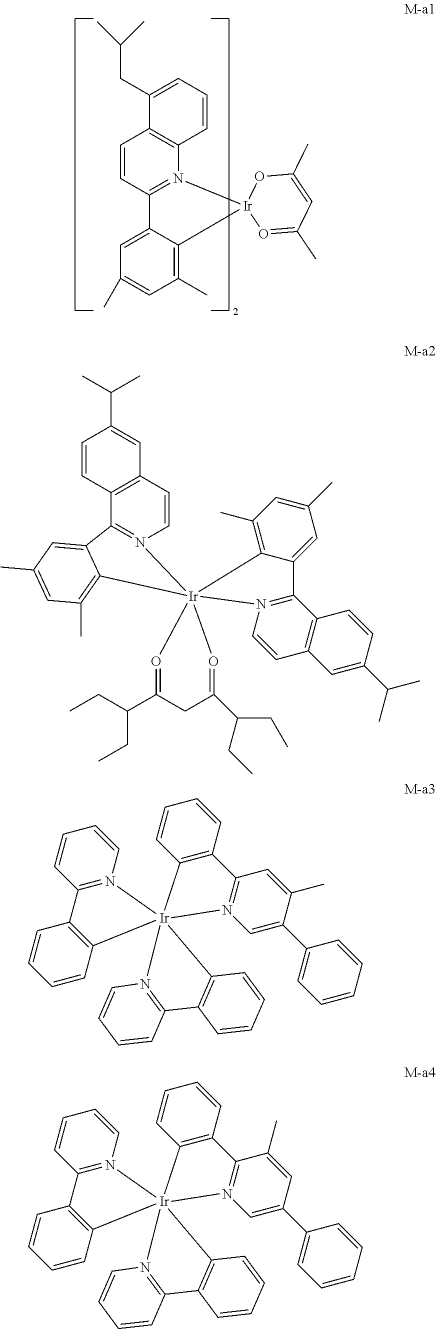

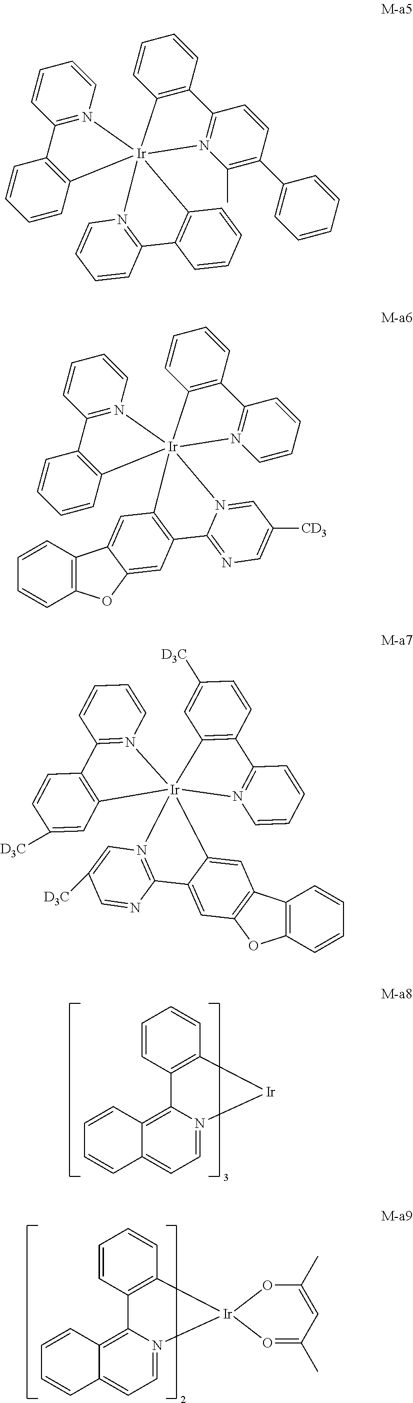

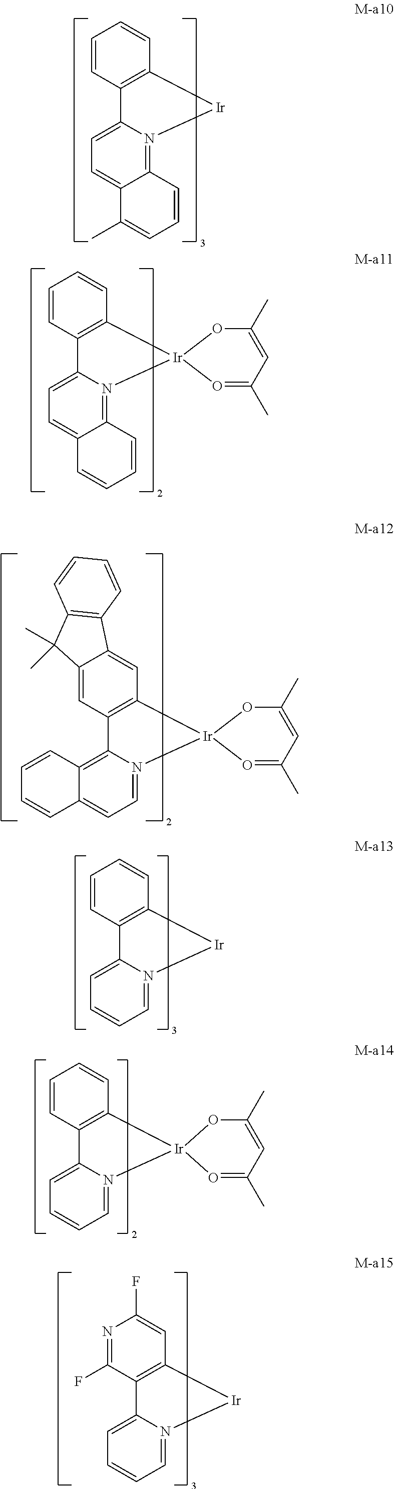

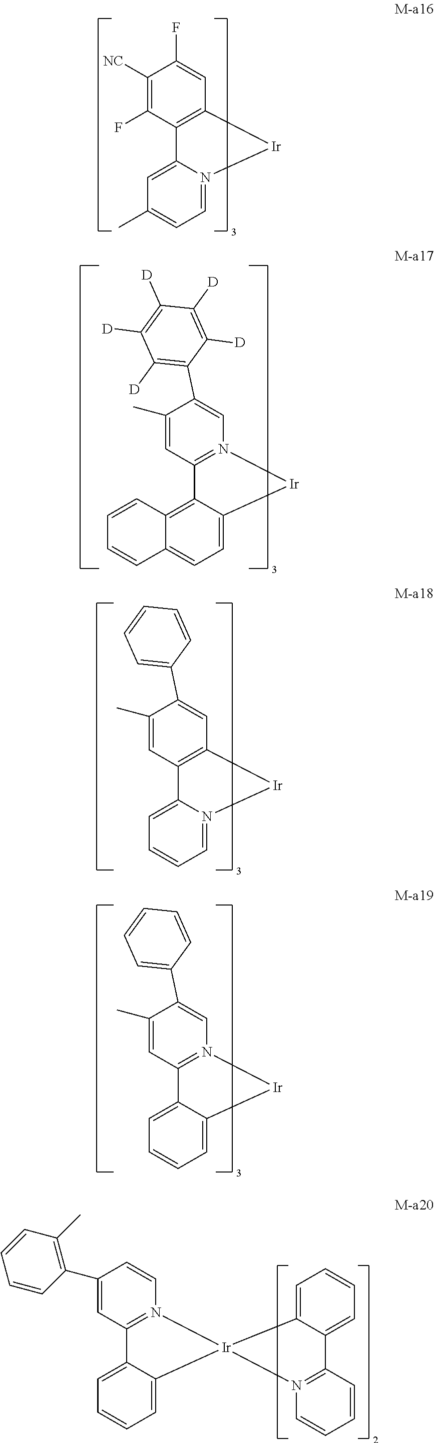

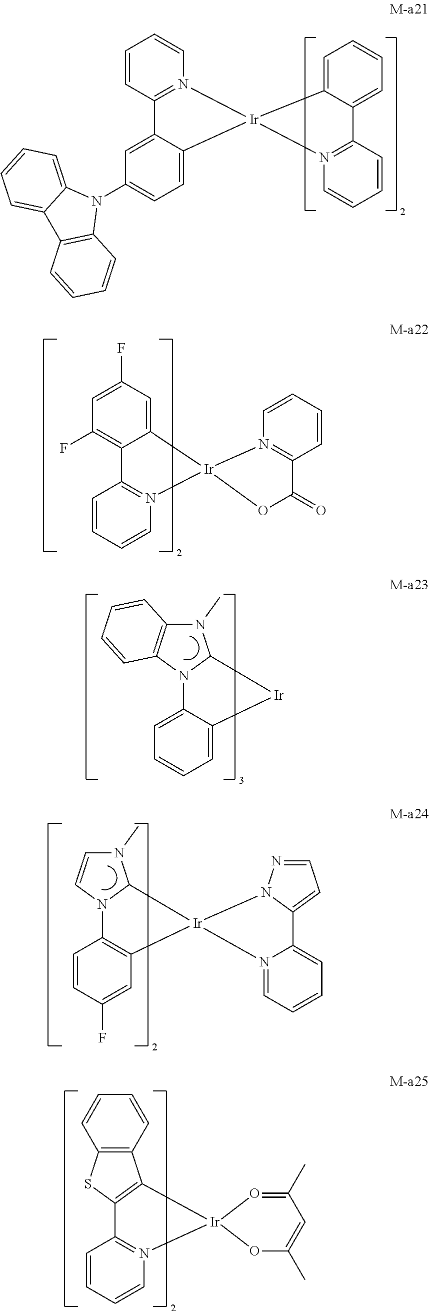

In one or more embodiments, the emission layer EML may include a compound represented by any one selected from among Formula F-a to Formula F-c. The compound represented by any one selected from among Formula F-a to Formula F-c may be used as a fluorescence dopant material.

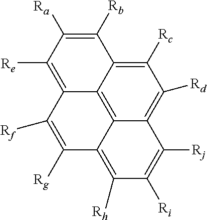

In Formula F-a, two selected from among Rₐ to Rⱼ may each independently be substituted with *—NAr₁Ar₂. The others, which are not substituted with *—NAr₁Ar₂, among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

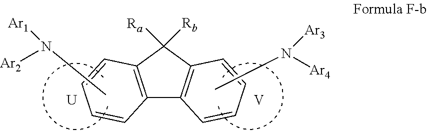

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) the number of U and the number of V are each 0, the fused ring in Formula F-b may be a cyclic compound having three rings. In one or more embodiments, if (e.g., when) the number of U and the number of V are each 1, the fused ring having a fluorene core in Formula F-b may be a cyclic compound having five rings.

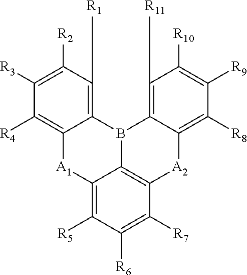

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Rᵢ to R₁₁ may each independently be hydrogen, deuterium, a halogen, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are independently bonded to an adjacent group to form a ring.

In one or more embodiments, in Formula F-c, A₁ and A₂ may each independently be bonded to substituents of an adjacent ring to form a fused ring. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, in one or more embodiments, iridium(III) bis(4,6-difluorophenylpyridinato-N, C2′)picolinate) (Flrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments of the present disclosure are not limited thereto.

In one or more embodiments, the emission layer EML may include a quantum dot material (e.g., quantum dot). In one or more embodiments, the quantum dot includes a core, and the core of a quantum dot may be selected from among a Group II-VI compound, a Group I-II-VI compound, a Group II-IV-VI compound, a Group I-II-IV-VI compound, a Group II-IV-V compound, a Group III-VI compound, a Group I-III-VI element, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; and a mixture thereof.

In one or more embodiments, the Group II-VI compound may may further include a Group I metal and/or a Group IV element. The Group I-II-VI compound may be selected from among CuSnS and/or CuZnS, and the Group II-IV-VI compound may be selected from among ZnSnS and/or the like. The Group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and a mixture thereof.

The Group II-IV-V compound may be selected from among a ternary compound selected from the group consisting of ZnSnP, ZnSnP₂, ZnSnAs₂, ZnGeP₂, ZnGeAs₂, CdSnP₂, and CdGeP₂ and a mixture thereof.

The Group III-VI compound may include a binary compound such as GaS, Ga₂S₃, GaSe, Ga₂Se₃, GaTe, InTe, InS, InSe, In₂S₃, and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from among the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and a mixture thereof. In one or more embodiments, the Group III-V compound may further include a Group II metal. For example, InZnP and/or the like may be selected as a Group III-II-V compound.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a multi-element compound such as the binary compound, the ternary compound, and the quaternary compound may be present in a particle at a substantially uniform concentration or a non-uniform concentration. For example, Formula above indicates the types (kinds) of elements included in a compound, and element ratios in the compound may be different. For example, AgInGaS₂ may indicate AgInₓGa₁₋ₓS² (x is a real number between 0 and 1).

In one or more embodiments, the quantum dot may have a single structure having a substantially uniform concentration of each element included in the corresponding quantum dot or a dual structure of core-shell. For example, materials included in the core may be different from materials included in the shell.

The shell of the quantum dot may serve as a protection layer to prevent or reduce the chemical deformation of the core so as to keep semiconductor properties, and/or a charging layer to impart electrophoresis properties to the quantum dot. The shell may be single-layered or multi-layered. An interface between the core and the shell may have a concentration gradient in which the concentration of an element present in the shell becomes lower towards the center.

In one or more embodiments, the quantum dot may have the above-described core/shell structure including a core having nano-crystals and a shell around (e.g., surrounding) the core. Examples of the shell of the quantum dot may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the present disclosure are not limited thereto.

In addition, the semiconductor compound suitable as a shell may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Each element included in a multi-element compound such as the binary compound and the ternary compound may be present in a particle at a substantially uniform concentration or a non-substantially uniform concentration. For example, Formula above indicates the types (kinds) of elements included in a compound, and element ratios in the compound may be different.

The quantum dot may have, in a light emitting wavelength spectrum (e.g., emission spectrum), a full width at half maximum (FWHM) of about 45 nm or less, about 40 nm or less, or about 30 nm or less, and in this range, color purity or color reproducibility of the quantum dot may be improved. In addition, light emitted through the quantum dot is emitted in all directions, and thus a wide viewing angle may be improved.

In addition, the form of the quantum dot is not particularly limited as long as it is a form commonly used in the art, for example, a quantum dot in the form of spherical nanoparticles, pyramidal nanoparticles, multi-arm nanoparticles, cubic nanoparticles, nanotubes, nanowires, nanofibers, nanoplatelets, and/or the like may be used.

As the size of the quantum dot or the ratio of elements in the quantum dot compound is regulated, the energy band gap thereof may be accordingly controlled or selected to obtain light of one or more suitable wavelengths from a quantum dot emission layer. Therefore, by using the quantum dots as described above (using quantum dots of different sizes and/or having different element ratios in the quantum dot compound), a light emitting element emitting light of one or more suitable wavelengths may be obtained. For example, the size of the quantum dot and/or the ratio of elements in the quantum dot compound may be regulated to enable the quantum dot to emit red color light, green color light, and/or blue color light. In addition, the quantum dots may be configured to emit white light by combining light of one or more suitable colors.

In each of the light emitting elements ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of the electron injection layer EIL or the electron transport layer ETL, and may have a single layer structure formed of an electron injection material and/or an electron transport material. In one or more embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order from the emission layer EML, but embodiments of the present disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

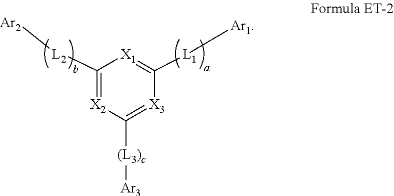

In Formula ET-2, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or greater, L₁ to L₃ each in plurality may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, for example, in one or more embodiments, the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof.

In one or more embodiments, the electron transport region ETR may include at least one selected from among Compound ET1 to Compound ET36:

[chemical structure]

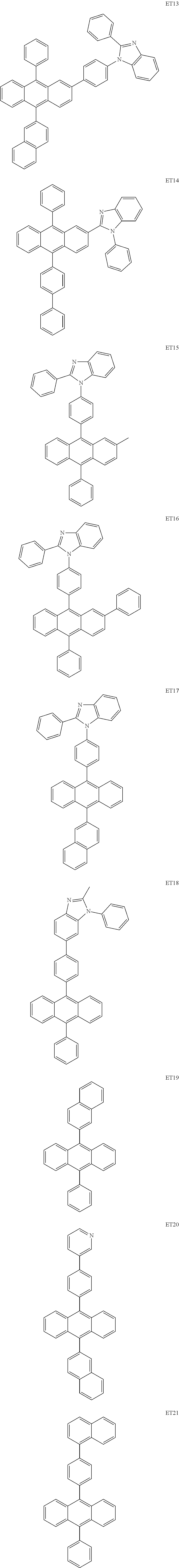

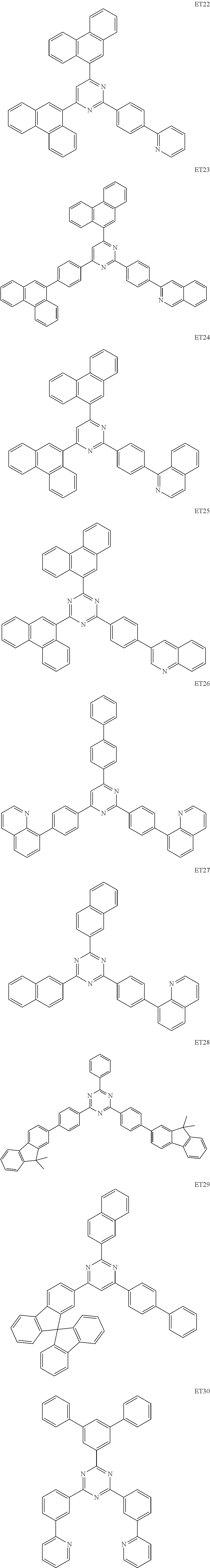

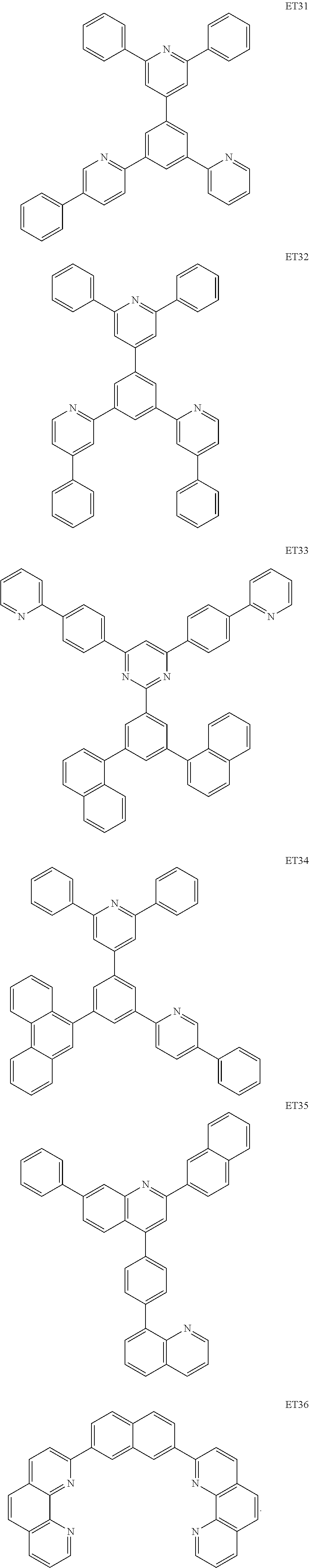

In one or more embodiments, the electron transport region ETR may include a metal halide such as LiF, NaCl, CsF, RbCl, RbI, CuI, and/or KI, a lanthanide metal such as Yb, or a co-deposited material of the metal halide and the lanthanide metal. For example, in one or more embodiments, the electron transport region ETR may include KI:Yb, RbI:Yb, LiF:Yb, and/or the like, as a co-deposited material. In one or more embodiments, the electron transport region ETR may be formed using a metal oxide such as Li₂O or BaO, or lithium-8-hydroxyquinolinolate (Liq), and/or the like, but embodiments of the present disclosure are not limited thereto. In one or more embodiments, the electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the present disclosure are not limited thereto.

The electron transport region ETR may include one or more of the above-described compounds of the hole transport region in at least one of the electron injection layer EIL, the electron transport layer ETL, or the hole blocking layer HBL.

If (e.g., when) the electron transport region ETR includes the electron transport layer ETL, the electron transport layer ETL may have a thickness of about 100 Å to about 1,000 Å, for example, about 150 Å to about 500 Å. If (e.g., when) the thickness of the electron transport layer ETL satisfies the aforementioned range, satisfactory electron transport characteristics may be obtained without a substantial increase in driving voltage. If (e.g., when) the electron transport region ETR includes the electron injection layer EIL, the electron injection layer EIL may have a thickness of about 1 Å to about 100 Å, for example, about 3 Å to about 90 Å. If (e.g., when) the thickness of the electron injection layer EIL satisfies the above-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, Na, or a compound or mixture thereof (e.g., AgMg, AgYb, MgYb, AgNa, or AgLi). In one or more embodiments, the second electrode EL2 may have a multilayer structure including a reflective film or a transflective film formed of one of the above-described materials, and a transparent conductive film formed of ITO, IZO, ZnO, ITZO, and/or the like. For example, in one or more embodiments, the second electrode EL2 may include one of the above-described metal materials, a combination of at least two metal materials of the above-described metal materials, an oxide of the above-described metal materials, and/or the like.

In one or more embodiments, the second electrode EL2 may be connected with an auxiliary electrode. If (e.g., when) the second electrode EL2 is connected with the auxiliary electrode, the resistance of the second electrode EL2 may be decreased.

In one or more embodiments, the capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

In one or more embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or may include an epoxy resin and/or an acrylate such as methacrylate. However, embodiments of the present disclosure are not limited thereto, for example, in one or more embodiments, the capping layer CPL may include at least one selected from among Compounds P1 to P5:

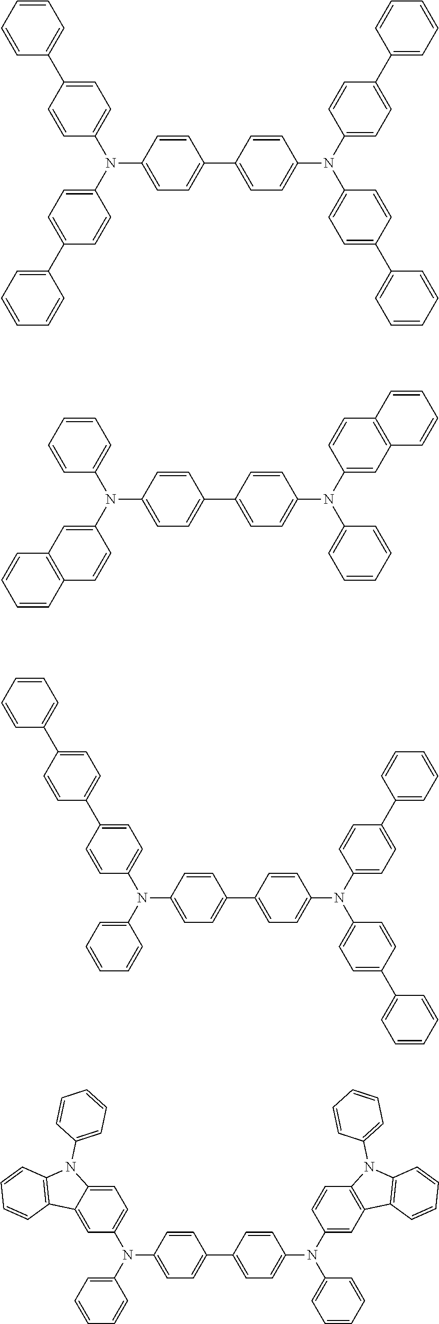 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

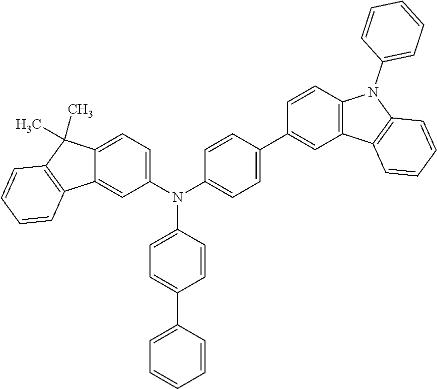 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL may be about 1.6 or more with respect to light in a wavelength range of about 550 nm to about 660 nm.

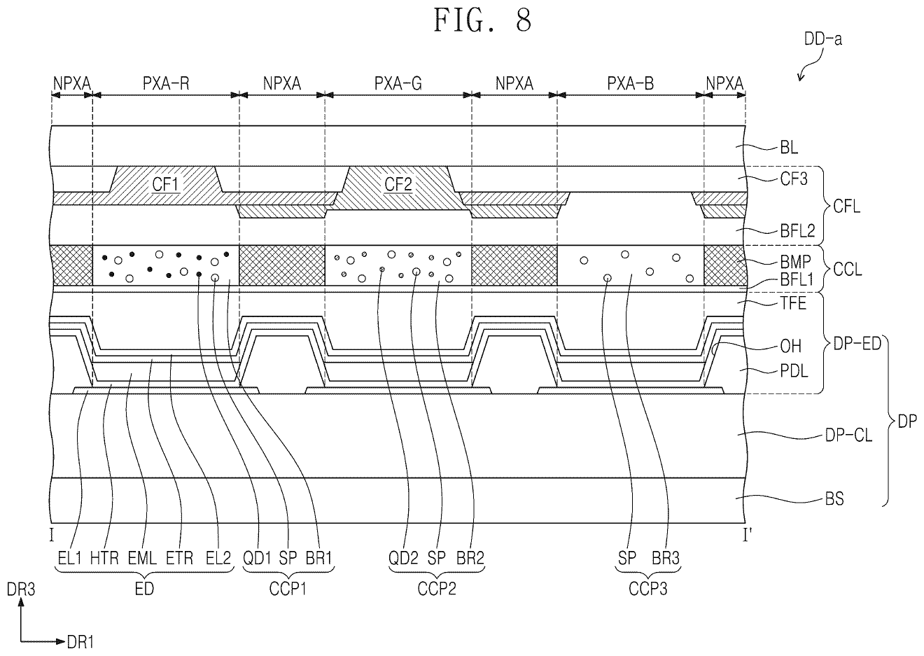

FIG. 8 to FIG. 11 are each a cross-sectional view of a display device according to one or more embodiments of the present disclosure. Hereinafter, in the explanation on the display devices according to one or more embodiments, referring to FIG. 8 to FIG. 11, the overlapping content with those explained in FIG. 1 to FIG. 6 will not be explained again, and different points will be explained mainly.

Referring to FIG. 8, a display device DD-a according to one or more embodiments may include a display panel DP including a display element layer DP-ED, a light controlling layer CCL arranged on the display panel DP, and a color filter layer CFL. In one or more embodiments shown in FIG. 8, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, a same structure as any one of the light emitting elements ED of FIG. 3 to FIG. 6 may be equally applied to the structure of the light emitting element ED, shown in FIG. 8. The light emitting element ED shown in FIG. 8 may include the fused polycyclic compound of one or more embodiments. The light emitting element ED including the fused polycyclic compound of one or more embodiments may exhibit long lifespan characteristics.

Referring to FIG. 8, the emission layer EML may be arranged in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue color light. In one or more embodiments, the emission layer EML may be provided as a common layer across the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, in one or more embodiments, the light control layer CCL may be a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 8, divided patterns BMP may be arranged between the light control parts CCP1, CCP2, and CCP3 which are spaced and/or apart (e.g., spaced apart or separated) from one another, but embodiments of the present disclosure are not limited thereto. FIG. 8 illustrates that the divided patterns BMP do not overlap the light control parts CCP1, CCP2, and CCP3, but, in one or more embodiments, at least a portion of the edges of each of the light control parts CCP1, CCP2, and CCP3 may overlap the divided patterns BMP.

In one or more embodiments, the light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red color light that is the second color light, and the second light control part CCP2 may provide green color light that is the third color light. The third light control part CCP3 may provide blue color light by transmitting the blue color light that is the first color light provided from the light emitting element ED. For example, the first quantum dot QD1 may be a red quantum dot to emit red color light, and the second quantum dot QD2 may be a green quantum dot to emit green color light. The same content on quantum dots described above may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed, accordingly. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed accordingly, and may be formed of one or more suitable resin compositions, which may be generally referred to as a binder. For example, the base resins BR1, BR2, and BR3 may be each independently selected from among acrylic-based resins, urethane-based resins, silicone-based resins, epoxy-based resins, and/or the like. The base resins BR1, BR2, and BR3 may each be a transparent resin. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may each independently further include an organic film. The barrier layers BFL1 and BFL2 may be each formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. For example, in one or more embodiments, the first filter CF1 may include a red pigment and/or a red dye, the second filter CF2 may include a green pigment and/or a green dye, and the third filter CF3 may include a blue pigment and/or a blue dye.

However, embodiments of the present disclosure are not limited thereto, for example, in one or more embodiments, the third filter CF3 may not include (e.g., may exclude) any pigment or any dye. The third filter CF3 may include a polymeric photosensitive resin and may not include (e.g., may exclude) a pigment or a dye. The third filter CF3 may be transparent. In one or more embodiments, the third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material and/or an inorganic light shielding material each containing a black pigment or a black dye. The light shielding part may prevent or reduce light leakage, and may separate boundaries between adjacent filters CF1, CF2, and CF3. In one or more embodiments, the light shielding part may be formed of a blue filter.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

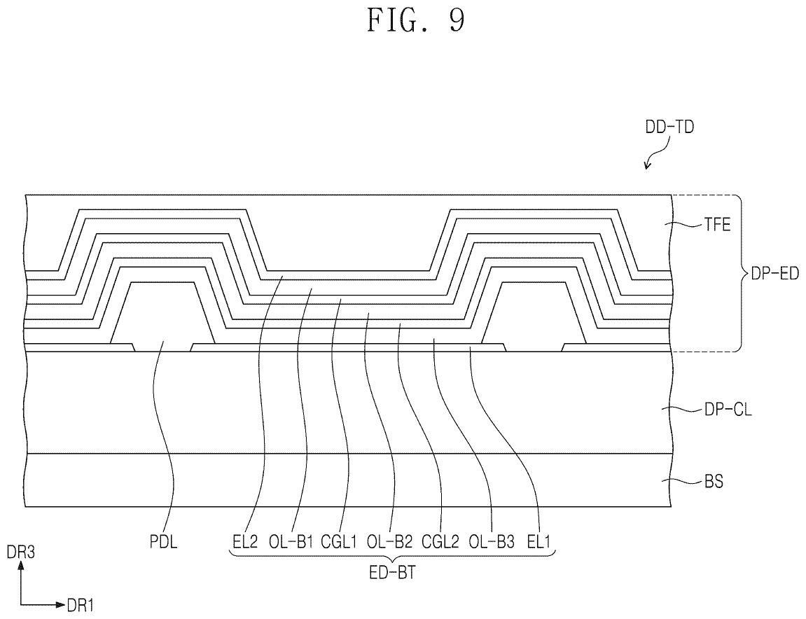

FIG. 9 is a cross-sectional view showing a portion of a display device according to one or more embodiments of the present disclosure. In a display device DD-TD of one or more embodiments, a light emitting element ED-BT may include multiple light emitting structures OL-B1, OL-B2, and OL-B3. The light emitting element ED-BT may include oppositely arranged first electrode EL1 and second electrode EL2, and multiple light emitting structures OL-B1, OL-B2, and OL-B3, which are stacked in order in a thickness direction (i.e., DR3) and provided between the first electrode EL1 and the second electrode EL2. Each of the light emitting structures OL-B1, OL-B2, and OL-B3 may include an emission layer EML (FIG. 8), and a hole transport region HTR and an electron transport region ETR, arranged with the emission layer EML (FIG. 8) therebetween. For example, the light emitting element ED-BT included in the display device DD-TD of one or more embodiments may be a light emitting element with a tandem structure, including multiple emission layers.

At least one selected from among the light emitting structures OL-B1, OL-B2, and OL-B3 may include the fused polycyclic compound of one or more embodiments. The light emitting element ED-BT including the fused polycyclic compound of one or more embodiments may exhibit long lifespan characteristics.

In one or more embodiments illustrated in FIG. 9, all light beams respectively emitted from the light emitting structures OL-B1, OL-B2, and OL-B3 may be blue color light. However, embodiments of the present disclosure are not limited thereto, for example, in one or more embodiments, the light beams respectively emitted from the light emitting structures OL-B1, OL-B2, and OL-B3 may have wavelength ranges different from one another. For example, in one or more embodiments, the light emitting element ED-BT including the plurality of light emitting structures OL-B1, OL-B2, and OL-B3 which emit light beams having wavelength ranges different from one another may be to emit white color light.

Charge generation layers CGL1 and CGL2 may be respectively arranged between neighboring light emitting structures OL-B1, OL-B2, and OL-B3. The charge generation layers CGL1 and CGL2 may each independently include a p-type (kind) charge generation layer and/or an n-type (kind) charge generation layer.

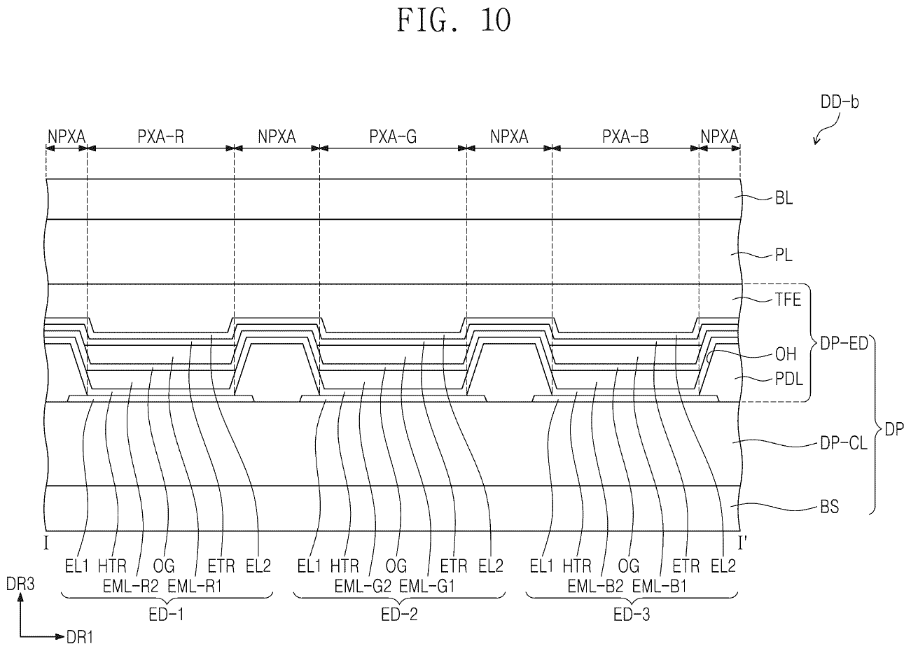

Referring to FIG. 10, a display device DD-b according to one or more embodiments may include light emitting elements ED-1, ED-2, and ED-3, in each of which two emission layers are stacked. Compared to the display device DD of one or more embodiments, shown in FIG. 2, embodiments shown in FIG. 10 differs in that each of first to third light emitting elements ED-1, ED-2, and ED-3 includes two emission layers stacked in a thickness direction. Two emission layers in each of the first to third light emitting elements ED-1, ED-2, and ED-3 may be to emit light having a same wavelength range.

At least one selected from among the light emitting elements ED-1, ED-2, and ED-3 may include the fused polycyclic compound of one or more embodiments. The at least one selected from among the light emitting elements ED-1, ED-2, and ED-3, including the fused polycyclic compound of one or more embodiments, may exhibit long lifespan characteristics.

According to one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2. In this regard, at least one of the first blue-color emission layer EML-B1 or the second blue-color emission layer EML-B2 may include the fused polycyclic compound of embodiments.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer across the whole of the first to third light emitting elements ED-1, ED-2, and ED-3. However, embodiments of the present disclosure are not limited thereto, for example, in one or more embodiments, the emission auxiliary part OG may be provided by being patterned within openings OH defined in a pixel defining film PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may each be arranged between the hole transport region HTR and the emission auxiliary part OG.

For example, in one or more embodiments, the first light emitting element ED-1 may include a first electrode EL1, a hole transport region HTR, the second red emission layer EML-R2, the emission auxiliary part OG, the first red emission layer EML-R1, an electron transport region ETR, and a second electrode EL2 that are sequentially stacked. The second light emitting element ED-2 may include a first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include a first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer PL may be arranged on the display element layer DP-ED. The optical auxiliary layer PL may include a polarizing layer. The optical auxiliary layer PL may be arranged on the display panel DP and control reflected light in the display panel DP due to external light. In one or more embodiments, the optical auxiliary layer PL may not be provided in the display device DD-b.

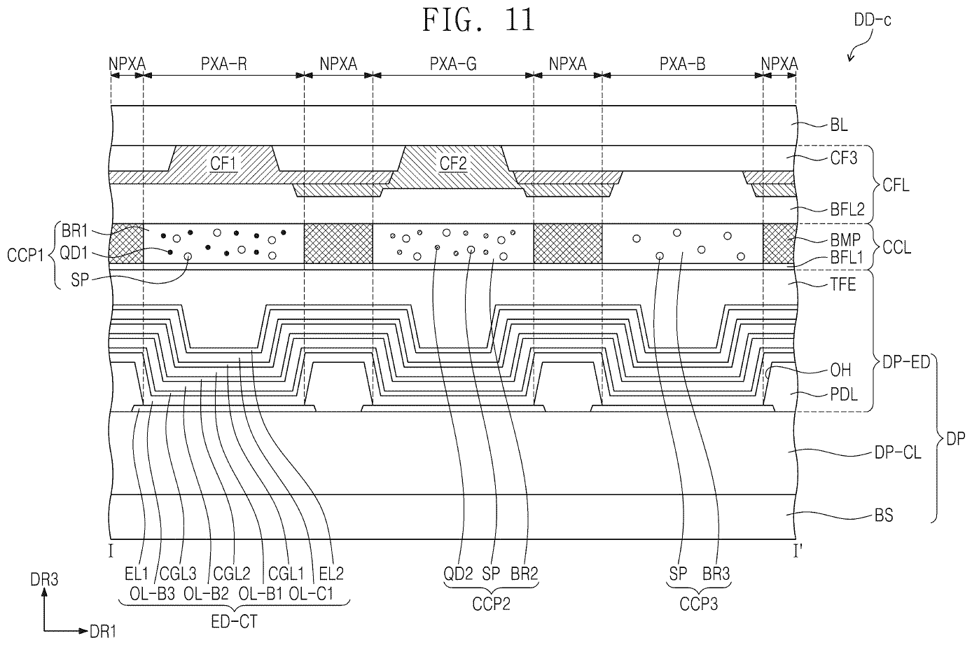

Different from FIG. 9 and FIG. 10, a display device DD-c in FIG. 11 is shown to include four light emitting structures OL-B1, OL-B2, OL-B3, and OL-C1. A light emitting element ED-CT may include oppositely arranged first electrode EL1 and second electrode EL2, and first to fourth light emitting structures OL-B1, OL-B2, OL-B3 and OL-C1 stacked in a thickness direction between the first electrode EL1 and the second electrode EL2. At least one selected from among the first to fourth light emitting structures OL-B1, OL-B2, OL-B3, and OL-C1 may include the fused polycyclic compound of one or more embodiments. The light emitting element ED-CT including the fused polycyclic compound of one or more embodiments may exhibit long lifespan characteristics.

Charge generation layers CGL1, CGL2, and CGL3 may be respectively arranged between neighboring first to fourth light emitting structures OL-B1, OL-B2, OL-B3, and OL-C1. Among the four light emitting structures, the first to third light emitting structures OL-B1, OL-B2, and OL-B3 may each be to emit blue color light, and the fourth light emitting structure OL-C1 may be to emit green color light. However, embodiments of the present disclosure are not limited thereto, for example, in one or more embodiments, the first to fourth light emitting structures OL-B1, OL-B2, OL-B3, and OL-C1 may be to emit light beams in different wavelength regions.

The charge generation layers CGL1, CGL2, and CGL3 respectively arranged between adjacent light emitting structures OL-B1, OL-B2, OL-B3, and OL-C1 may each include a p-type (kind) charge generation layer and/or an n-type (kind) charge generation layer.

In one or more embodiments, an electronic apparatus may include a display device including multiple light emitting elements and a control part configured to control the display device. The electronic apparatus of one or more embodiments may be a device activated according to electrical signals. The electronic apparatus may include display devices of various embodiments. For example, the electronic apparatuses may include large-size display devices such as televisions, monitors, and outside billboards, and medium- and small-size display devices such as personal computers, laptop computers, personal digital terminals, display apparatuses for automobiles, game consoles, portable electronic apparatuses, and cameras.

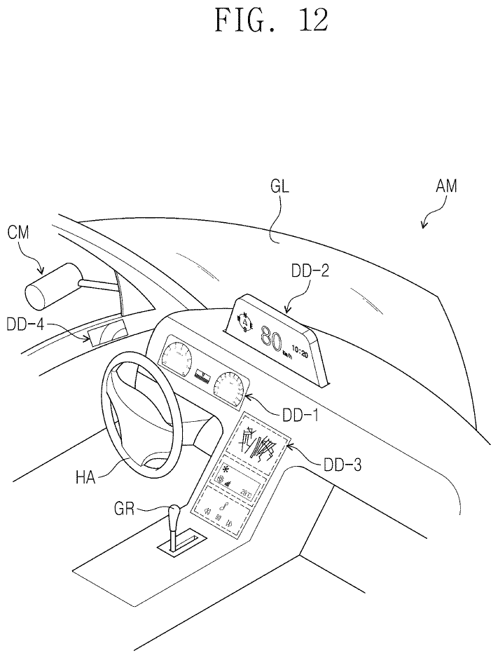

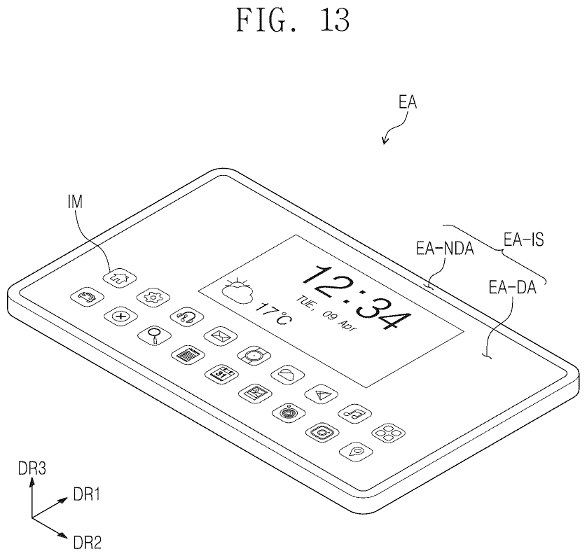

FIG. 12 is a diagram showing an automobile AM in which first to fourth display devices DD-1, DD-2, DD-3, and DD-4 are arranged. At least one selected from among the first to fourth display devices DD-1, DD-2, DD-3, and DD-4 may include a configuration selected from among the configurations of the display devices DD, DD-TD, DD-a, DD-b, and DD-c of embodiments, explained referring to FIGS. 1, 2, and 8 to 11.

In FIG. 12, a vehicle is shown as an automobile AM, but this is an example, and the first to fourth display devices DD-1, DD-2, DD-3, and DD-4 may be arranged on other transport apparatuses such as bicycles, motorcycles, trains, ships, and airplanes. In one or more embodiments, at least one selected from among the first to fourth display devices DD-1, DD-2, DD-3, and DD-4 including the same configuration as one of the display devices DD, DD-TD, DD-a, DD-b and DD-c may be introduced in personal computers, laptop computers, personal digital terminals, game consoles, portable electronic devices, televisions, monitors, external billboards, and/or the like. In addition, these are suggested as examples, and the display device may be introduced in other electronic apparatuses as long as not deviated from the teachings of the present disclosure.

At least one selected from among the first to fourth display devices DD-1, DD-2, DD-3, and DD-4 may include the light emitting element ED, explained referring to FIG. 3 to FIG. 6. At least one selected from among the first to fourth display devices DD-1, DD-2, DD-3, and DD-4 may include the fused polycyclic compound of one or more embodiments. The display device including the fused polycyclic compound of one or more embodiments (the at least one selected from among the first to fourth display devices DD-1, DD-2, DD-3, and DD-4) may show excellent or suitable display quality and excellent or suitable reliability.

Referring to FIG. 12, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. In one or more embodiments, the first scale and the second scale may be indicated as a digital image.

The second display device DD-2 may be arranged in a second region opposite to (e.g., facing) a driver seat and overlapping the front window GL. The driver seat may be a seat in which the steering wheel HA faces. For example, the second display device DD-2 may be a head up display (HUD) which displays second information of the vehicle AM. In one or more embodiments, the second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between the driver seat and a passenger seat and may be a center information display (CID) for the vehicle for displaying third information. The passenger seat may be a seat spaced from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced from the steering wheel HA and the gear GR, and may be arranged in a fourth region adjacent to a side of the vehicle AM. For example, in one or more embodiments, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information are examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include the same information as one another.

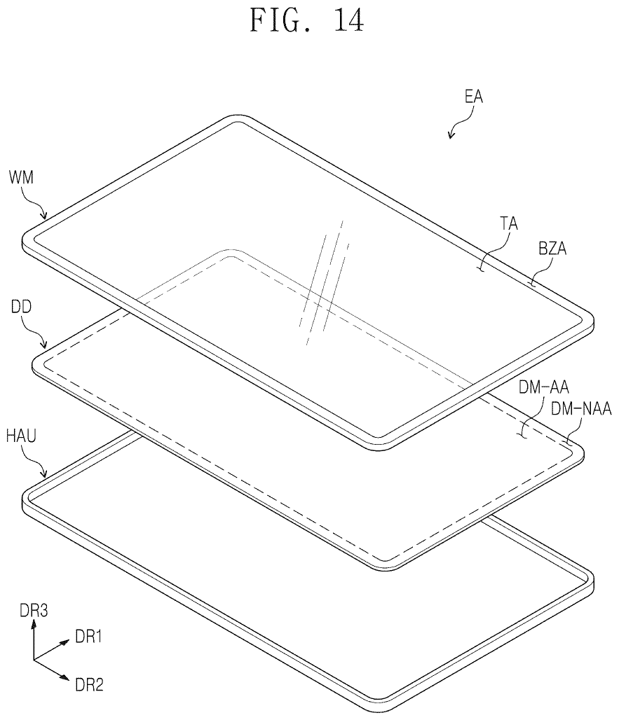

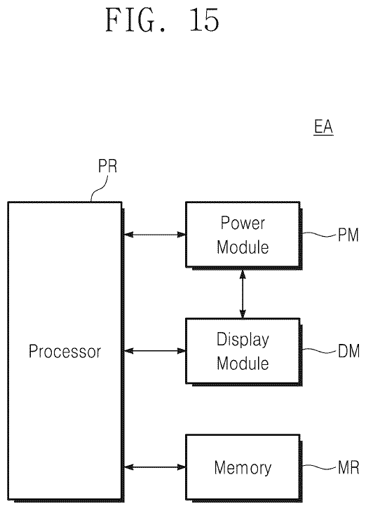

FIG. 13 is a perspective view showing an electronic apparatus according to one or more embodiments of the present disclosure. FIG. 14 is an exploded perspective view showing an electronic apparatus according to one or more embodiments of the present disclosure.

In FIG. 13, a portable electronic apparatus is presented as an example of an electronic apparatus EA. The electronic apparatus EA may display an image IM through a display surface EA-IS. The image IM may include still images as well as dynamic images. The display surface EA-IS may be parallel to a plane defined by a first direction axis DR1 and a second direction axis DR2. FIG. 13 shows the electronic apparatus EA provided with a flat display surface EA-IS, but embodiments of the present disclosure are not limited thereto. For example, in one or more embodiments, the electronic apparatus EA may include a curved display surface or a three-dimensional display surface. The three-dimensional display surface may include a plurality of display regions indicating different directions.

The display surface EA-IS may include a display region EA-DA and a non-display region EA-NDA. The electronic apparatus EA may display the image IM through the display region EA-DA.

The non-display region EA-NDA may have a set or predetermined color. The non-display region EA-NDA may be adjacent to the display region EA-DA. In one or more embodiments, the non-display region EA-NDA may surround the display region EA-DA. Accordingly, a shape of the display region EA-DA may be defined substantially by the non-display region EA-NDA. However, FIG. 13 is presented as an example, in one or more embodiments, the non-display region EA-NDA may be arranged adjacent to only one side of the display region EA-DA, or may not be provided.

Referring to FIG. 14, the electronic apparatus EA may include a display device DD. In addition, the electronic apparatus EA may further include a window member WM and a housing HAU.

The window member WM may cover an entire outer portion of the electronic apparatus EA. The window member WM may include a transmission region TA and a bezel region BZA. A front surface of the window member WM including the transmission region TA and the bezel region BZA may serve as a front surface of the electronic apparatus EA. The transmission region TA may correspond to the display region EA-DA of the electronic apparatus EA shown in FIG. 13, and the bezel region BZA may correspond to the non-display region EA-NDA of the electronic apparatus EA shown in FIG. 13.

The transmission region TA may be an optically transparent region. The bezel region BZA may be a region having a relatively lower light transmittance than the transmission region TA. The bezel region BZA may have a prescribed or preset color. The bezel region BZA may be adjacent to the transmission region TA and may surround the transmission region TA. The bezel region BZA may define a shape of the transmission region TA. However, embodiments of the present disclosure are not limited to what is shown, for example, in one or more embodiments, the bezel region BA may be arranged adjacent to only one side of the transmission region TA, and a portion thereof may not be provided.

The housing HAU may include a material having a relatively greater rigidity. In one or more embodiments, the housing HAU may include frames and/or plates formed of glass, plastic, or metal. The frames and/or plates may be provided in plurality. The housing HAU may provide a prescribed place for accommodation. The display device DD may be accommodated in the accommodation place to be protected from external shocks.

The display device DD may have a same configuration as at least one selected from among the display devices DD, DD-TD, DD-a, DD-b, and DD-c according to one or more embodiments described with reference to FIGS. 1, 2, and 8 to 11. The display device DD may include one of the light emitting elements ED described with reference to FIGS. 3 to 6. Accordingly, the electronic apparatus EA including the display device DD according to one or more embodiments may exhibit excellent or suitable reliability.

The display device DD may be activated according to electrical signals and may provide the image IM (FIG. 13). The display device DD may be activated to display the image IM (FIG. 13) on the display region EA-DA (FIG. 13) of the electronic apparatus EA. In the display device DD, an active region DM-AA and a peripheral region DM-NAA may be defined. The active region DM-AA may overlap the display region EA-DA shown in FIG. 13, and the peripheral region DM-NAA may overlap the non-display region EA-NDA shown in FIG. 13.

The active region DM-AA may be a region activated according to electrical signals. The peripheral region DM-NAA may be a region adjacent to at least one side of the active region DM-AA. The active region DM-AA may include a non-light emitting region NPXA and light emitting regions PXA-R, PXA-G, and PXA-R shown in FIG. 1. The peripheral region DM-NAA may surround the active region DM-AA. However, embodiments of the present disclosure are not limited thereto, for example, in one or more embodiments, a portion of the peripheral region DM-NAA may not be provided. A driving circuit, a driving line, and/or the like for driving the active region DM-AA may be arranged in the peripheral region DM-NAA.

Display devices selected from among display devices DD, DD-TD, DD-a, DD-b, and DD-c (FIGS. 1, 2, and 8 to 11) may be applied to one or more suitable electronic apparatuses. The electronic apparatus EA according to one or more embodiments may include one or more of the display devices DD, DD-TD, DD-a, DD-b, and DD-c (FIGS. 1, 2, and 8 to 11) described above, and may further include modules or devices having additional functions in addition to one or more of the display devices DD, DD-TD, DD-a, DD-b, and DD-c (FIGS. 1, 2, and 8 to 11).

FIG. 15 is a block diagram of an electronic apparatus according to one or more embodiments of the present disclosure. Referring to FIG. 15, an electronic apparatus EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information desired or required for operations of the processor PR and/or the display module DM. When the processor PR executes an application stored in the memory MR, image data signals and/or input control signals are transmitted to the display module DM, and the display module DM may process the received signal and output image information through a display screen.

The power module PM may include a power supply module such as a power adapter or a battery device, and a power conversion module that converts power supplied by the power supply module to generate power desired or required for an operation of the electronic apparatus EA.

At least one selected from among the components of the electronic apparatus EA described above may be included in the display device according to the above-described embodiments. In addition, some of the individual modules functionally included in one module may be included in the display device, and others may be separately provided from the display device. For example, the display device may include the display module DM, and the processor PR, the memory MR, and the power module PM may be provided in the form of other devices within the electronic apparatus EA, rather than the display device.

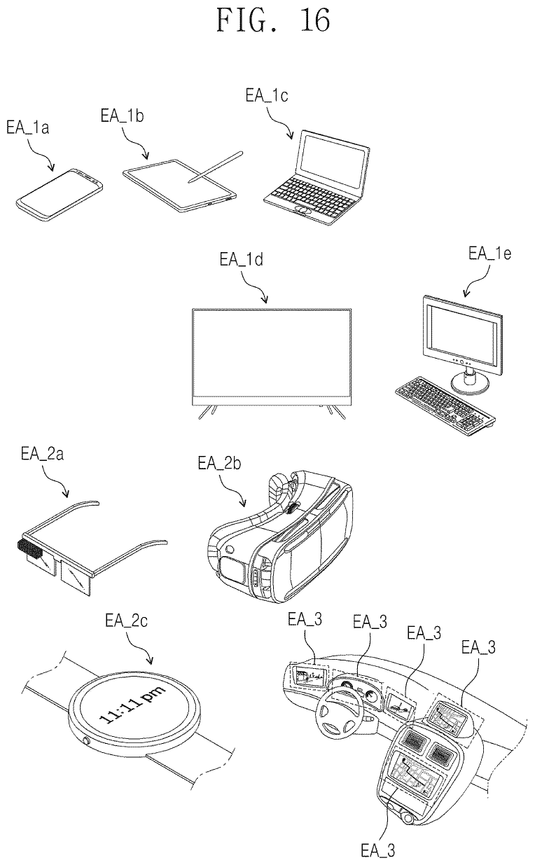

FIG. 16 shows schematic views of electronic apparatuses according to one or more embodiments of the present disclosure. Referring to FIG. 16, one or more suitable electronic apparatuses to which the display device according to one or more embodiments is applied may include an electronic apparatus for displaying images, such as a smart phone EA_1a, a tablet PC EA_1b, a laptop EA_1c, a TV EA_1d, and a desk monitor EA_1e, a wearable electronic apparatus including a display module such as a smart glasses EA_2a, a head mounted display EA_2b, and a smart watch EA_2c, and a vehicle electronic apparatus EA_3 including a display module such as a center information display (CID), a room mirror display arranged on an instrument panel, a center fascia, and/or a dashboard of a vehicle.

Hereinafter, with reference to Examples and Comparative Examples, a fused polycyclic compound and a light emitting element according to one or more embodiments of the present disclosure will be specifically described. However, Examples below are shown only to facilitate understanding of the disclosure, and the scope of the disclosure is not limited thereto.

### EXAMPLES

### 1. Synthesis of Fused Polycyclic Compounds of Examples

A process of synthesizing the fused polycyclic compound according to one or more embodiments will be described in more detail by presenting processes of synthesizing fused polycyclic Compounds 398, 503, 839, 1043, 1074, 1117, 1171, and 1280. In addition, the process of synthesizing fused polycyclic compounds, which will be described hereinafter, is provided as an example, and thus the process of synthesizing fused polycyclic compounds according to one or more embodiments of the disclosure is not limited to Examples provided herein.

### (1) Synthesis of Fused Polycyclic Compound 398

Fused polycyclic Compound 398 according to one or more embodiments may be synthesized through, for example, a process of Reaction Scheme1.

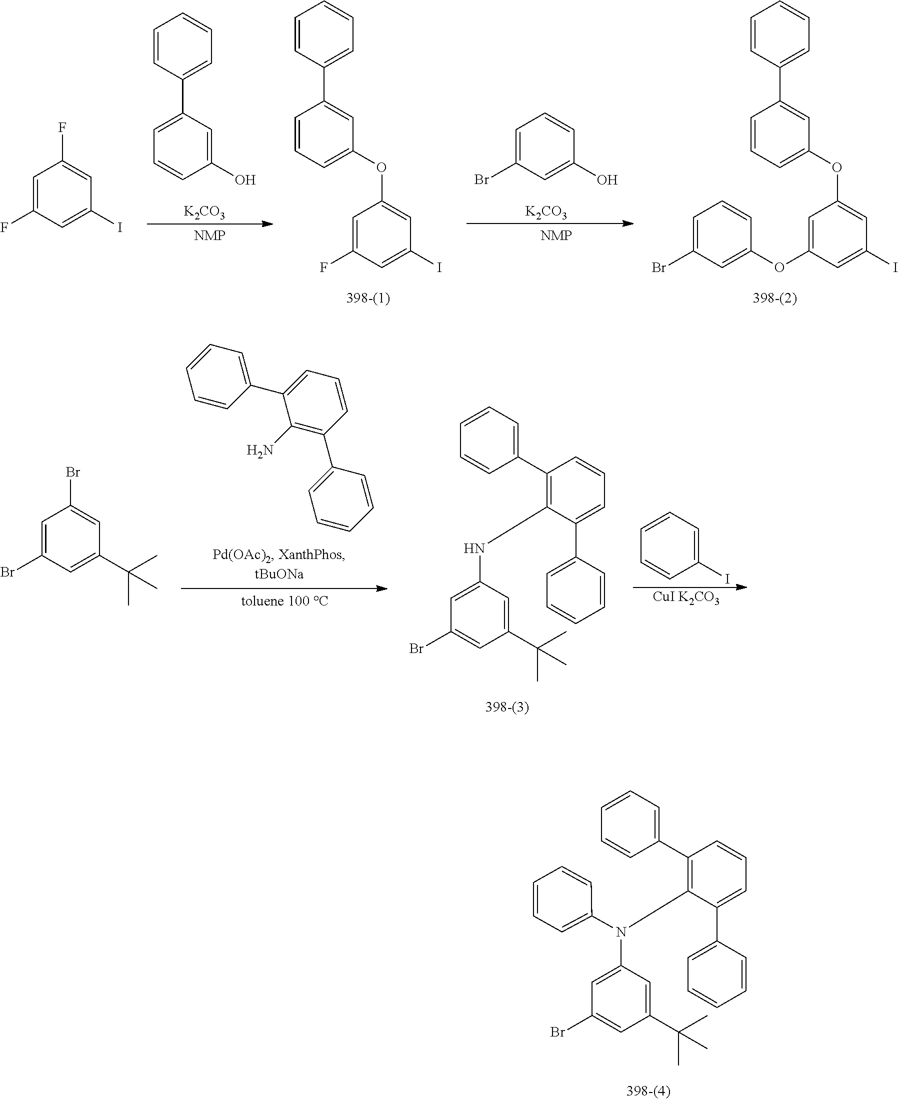

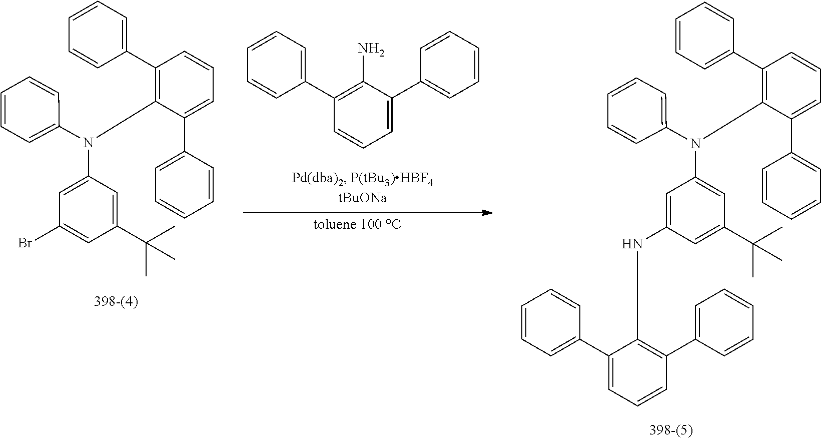

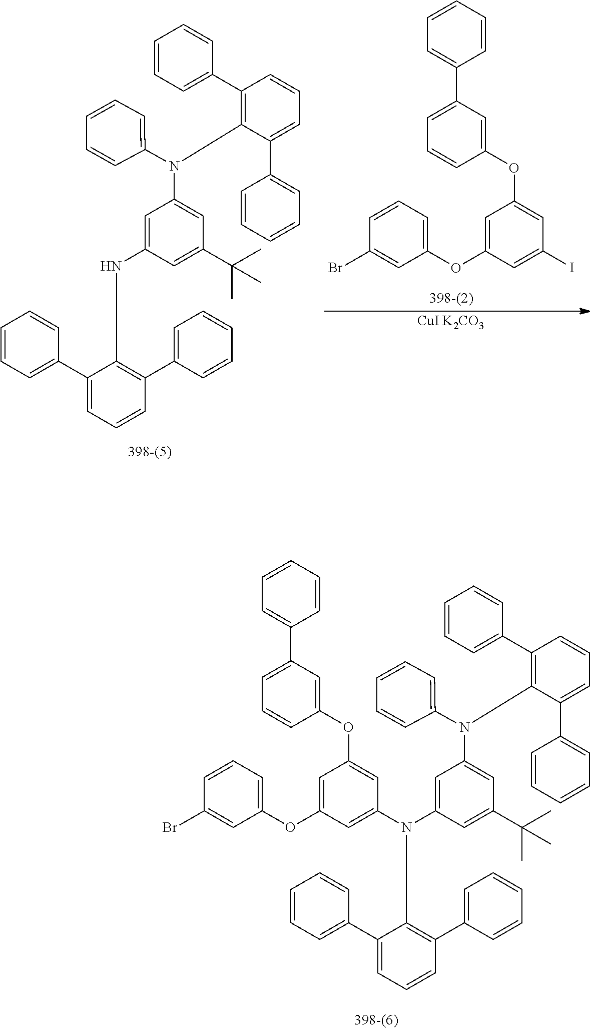 [SMILES: CC(C)(C)c1cc(Nc2c(-c3ccccc3)cccc2-c2ccccc2)cc(N(c2ccccc2)c2c(-c3ccccc3)cccc2-c2ccccc2)c1 ; Brc1cccc(Oc2cc(I)cc(Oc3cccc(-c4ccccc4)c3)c2)c1 ; "CuI K2CO3" ; CC(C)(C)c1cc(N(c2ccccc2)c2c(-c3ccccc3)cccc2-c2ccccc2)cc(N(c2cc(Oc3cccc(Br)c3)cc(Oc3cccc(-c4ccccc4)c3)c2)c2c(-c3ccccc3)cccc2-c2ccccc2)c1]

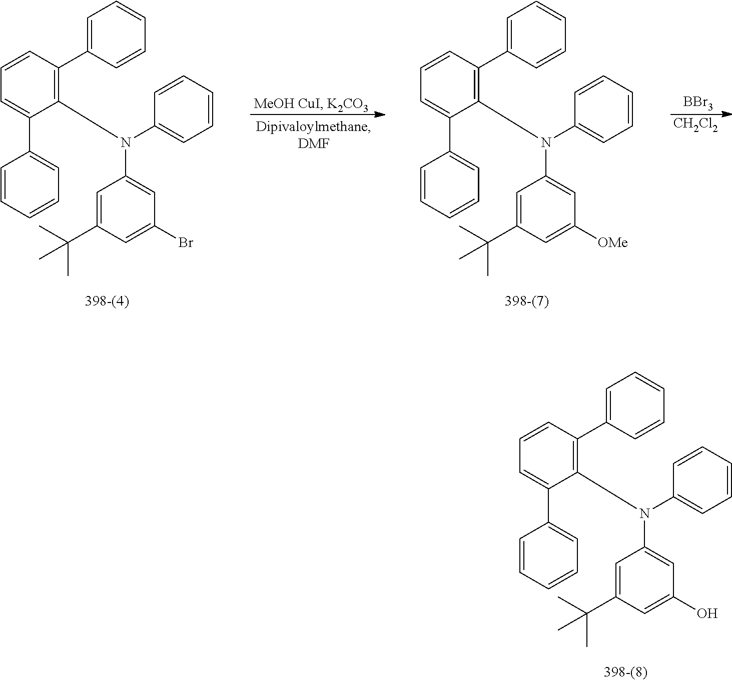

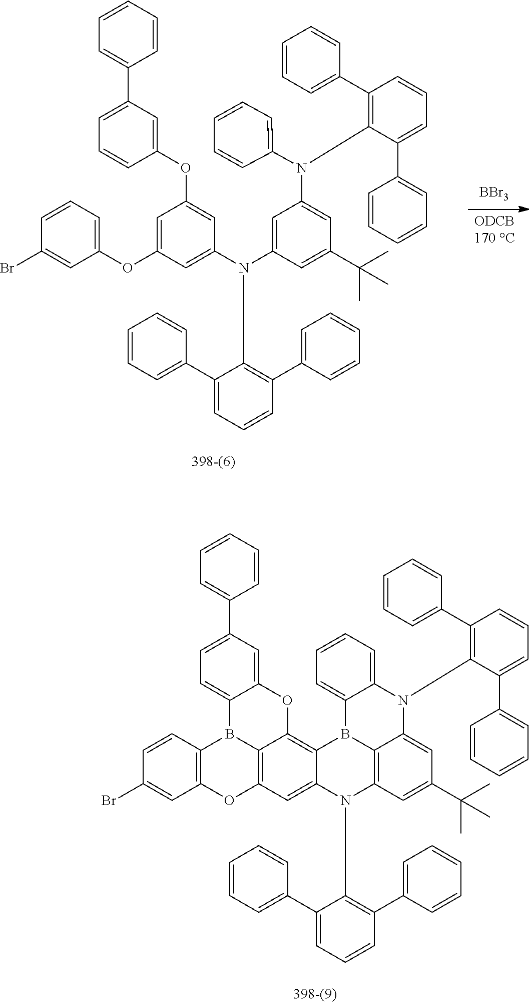

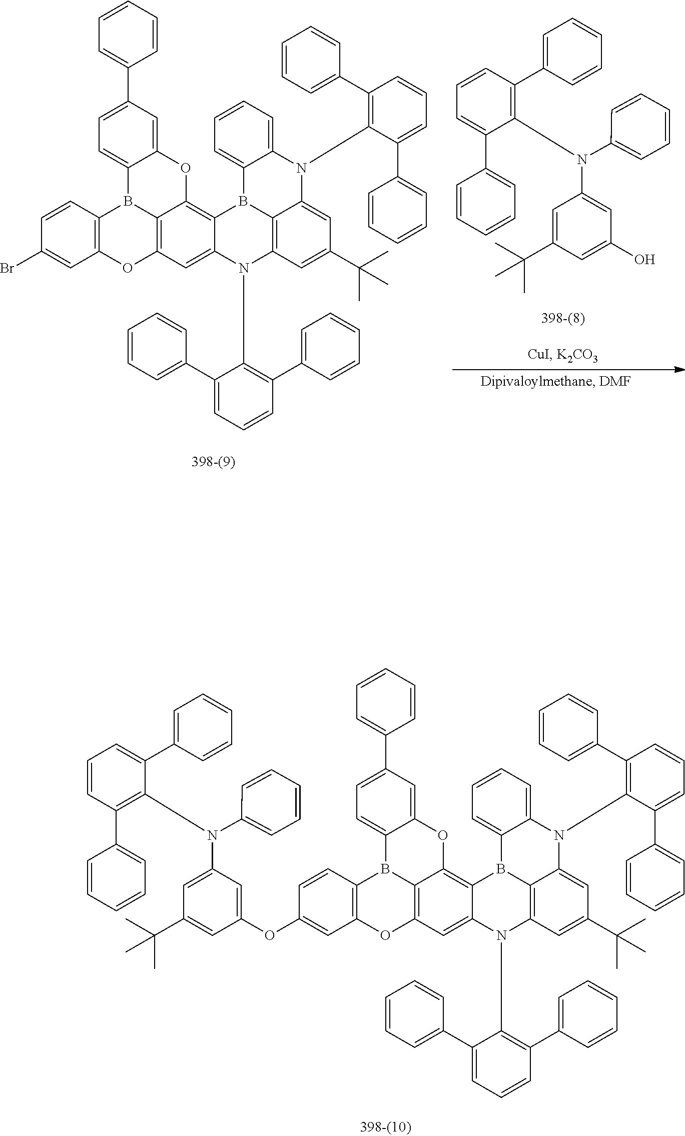

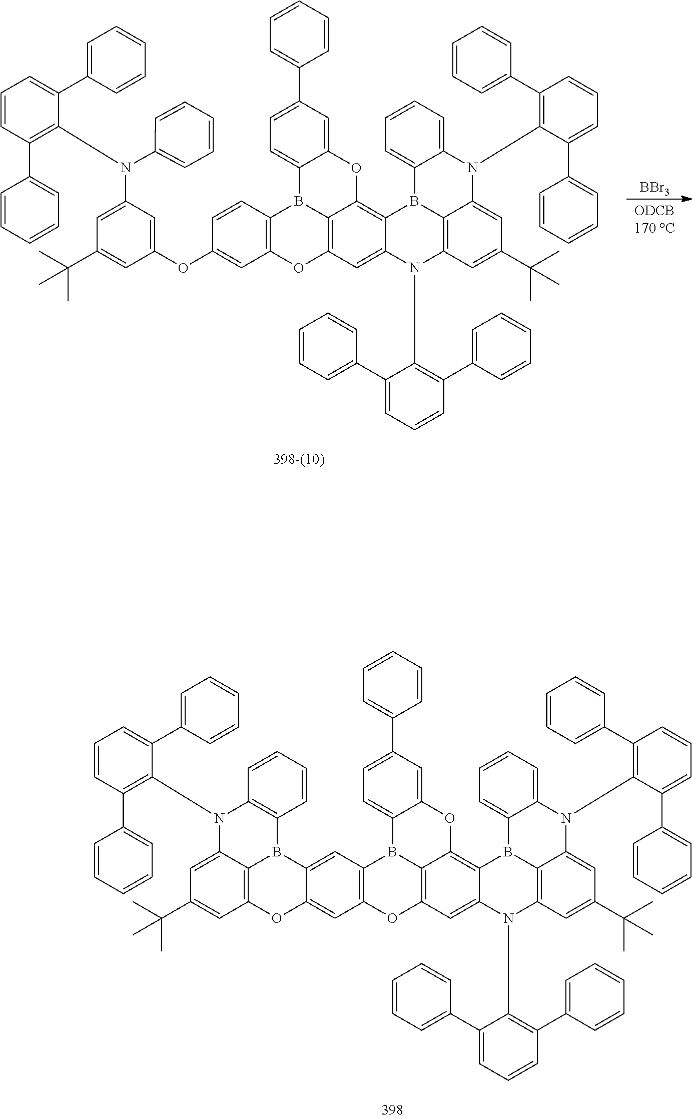

### Synthesis of Intermediate 398-(1)

In an Ar atmosphere, n-methyl-2-pyrrolidinone (NMP, 102 mL) was added to 1,3-difluoro-5-iodobenzene (10.2 g, 42.5 mmol), [1,1′-biphenyl]-3-ol (7.23 g, 42.5 mmol), and K₂CO₃ (26.43 g, 191.26 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(1) (14.10 g, yield: 85%). As measured by Fast Atom Bombardment Mass spectrometry (FAB MS), Intermediate 398-(1) had a molecular weight of 390.

### Synthesis of Intermediate 398-(2)

In an Ar atmosphere, NMP (139 mL) was added to Intermediate 398-(1) (13.91 g, 35.67 mmol), 3-bromophenol (6.17 g, 35.67 mmol), and K₂CO₃ (22.18 g, 160.5 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(2) (17.05 g, yield: 88%). As measured by FAB MS, Intermediate 398-(2) had a molecular weight of 543.

### Synthesis of Intermediate 398-(3)

In an Ar atmosphere, 1,3-dibromo-5-(tert-butyl)benzene (10.11 g, 34.62 mmol), [1,1′:3′,1″-terphenyl]-2′-amine (8.49 g, 34.62 mmol), palladium(II) acetate (Pd(OAc)₂) (0.23 g, 1.04 mmol), 4,5-bis(diphenylphosphino)-9,9-dimethylxanthene (XantPhos) (1.2 g, 2.08 mmol), and sodium tert-butoxide (tBuONa) (3.99 g, 41.55 mmol) were added to toluene (173 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 398-(3) (15.01 g, yield: 95%). As measured by FAB MS, Intermediate 398-(3) had a molecular weight of 456.

### Synthesis of Intermediate 398-(4)

Intermediate 398-(3) (14.22 g, 31.15 mmol), iodobenzene (50.85 g, 249.24 mmol), CuI (14.83 g, 77.89 mmol), and K₂CO₃ (64.59 g, 467.32 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(4) (11.95 g, yield: 72%). As measured by FAB MS, Intermediate 398-(4) had a molecular weight of 533.

### Synthesis of Intermediate 398-(5)

In an Ar atmosphere, Intermediate 398-(4) (10.55 g, 19.81 mmol), [1,1′:3′,1″-terphenyl]-2′-amine (5.83 g, 23.77 mmol), bis(dibenzylideneacetone)palladium(0) Pd(dba)₂) (1.14 g, 1.98 mmol), tri-tert-butylphosphonium tetrafluoroborate (P(tBu)₃·HBF₄) (1.15 g, 3.96 mmol), and tBuONa (4.38 g, 45.57 mmol) were added to toluene (99 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 398-(5) (11.6 g, yield: 84%). As measured by FAB MS, Intermediate 398-(5) had a molecular weight of 697.

### Synthesis of Intermediate 398-(6)

Intermediate 398-(5) (2.73 g, 3.92 mmol), Intermediate 398-(2) (17.04 g, 31.38 mmol), CuI (1.87 g, 9.81 mmol), and K₂CO₃ (8.13 g, 58.83 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(6) (3.1 g, yield: 71%). As measured by FAB MS, Intermediate 398-(6) had a molecular weight of 1112.

### Synthesis of Intermediate 398-(7)

Intermediate 398-(4) (10.05 g, 18.87 mmol), MeOH (methanol, 1.27 g, 39.63 mmol), CuI (3.95 g, 20.76 mmol), K₂CO₃ (10.43 g, 75.49 mmol), and dipivaloylmethane (39.54 g, 0.21 mmol) were added to dimethyl formamide (DMF, 395 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(7) (7.48 g, yield: 82%). As measured by FAB MS, Intermediate 398-(7) had a molecular weight of 484.

### Synthesis of Intermediate 398-(8)

In an Ar atmosphere, Intermediate 398-(7) (6.11 g, 12.63 mmol) was dissolved in CH₂Cl₂ (dichloromethane, 126 mL), BBr₃ (7.91 g, 31.58 mmol) was added, and the mixture was stirred at 0 °C for 24 hours. The reaction solution was added to ice water (306 mL), and the mixture was stirred for 1 hour and subjected to liquid separation to concentrate an organic layer. The concentrated organic layer was purified through silica gel column chromatography to obtain Intermediate 398-(8) (3.03 g, yield: 51%). As measured by FAB MS, Intermediate 398-(8) had a molecular weight of 470.

### Synthesis of Intermediate 398-(9)

In an Ar atmosphere, Intermediate 398-(6) (3.01 g, 2.71 mmol) was dissolved in o-dichlorobenzene (ODCB) (27 mL), BBr₃ (2.71 g, 10.83 mmol) was added, and the mixture was heated and stirred at 170 °C for 10 hours. The reaction solution was cooled to room temperature, N,N-diisopropylethylamine (DIPEA) (4.19 g, 32.48 mmol) was added, and water was added, and then the mixture was subjected to celite filtering and liquid separation to concentrate an organic layer. The concentrated organic layer was purified through silica gel column chromatography to obtain Intermediate 398-(9) (0.76 g, yield: 25%). As measured by FAB MS, Intermediate 398-(9) had a molecular weight of 1128.

### Synthesis of Intermediate 398-(10)

Intermediate 398-(9) (0.73 g, 0.65 mmol), Intermediate 398-(8) (0.3 g, 0.65 mmol), CuI (0.14 g, 0.71 mmol), K₂CO₃ (0.36 g, 2.59 mmol), and dipivaloylmethane (1.36 g, 0.01 mmol) were added to DMF (13 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 398-(10) (0.82 g, yield: 84%). As measured by FAB MS, Intermediate 398-(10) had a molecular weight of 1517.

### Synthesis of Compound 398

In an Ar atmosphere, Intermediate 398-(10) (0.81 g, 0.53 mmol) was dissolved in ODCB (5 mL), BBr₃ (0.53 g, 2.12 mmol) was added, and the mixture was heated and stirred at 170 °C for 10 hours. The reaction solution was cooled to room temperature, DIPEA (0.82 g, 6.37 mmol) was added, and water was added, and then the mixture was subjected to celite filtering and liquid separation to concentrate an organic layer. The concentrated organic layer was purified through silica gel column chromatography to obtain Compound 398 (0.35 g, yield: 43%). The FAB MS measurement shows that Compound 398 had a molecular weight of 1524. The obtained Compound 398 was subjected to sublimation purification (380 °C, 2.2×10−3 Pa) and used to prepare a light emitting element.

### (2) Synthesis of Fused Polycyclic Compound 503

Fused polycyclic Compound 503 according to one or more embodiments may be synthesized through, for example, a process of Reaction Scheme 2.

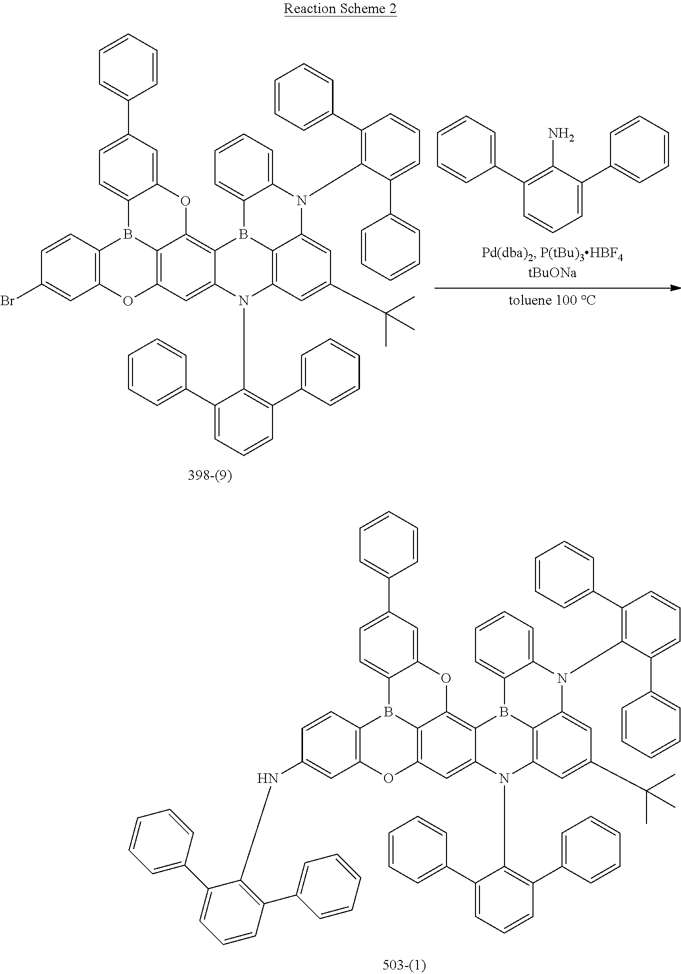

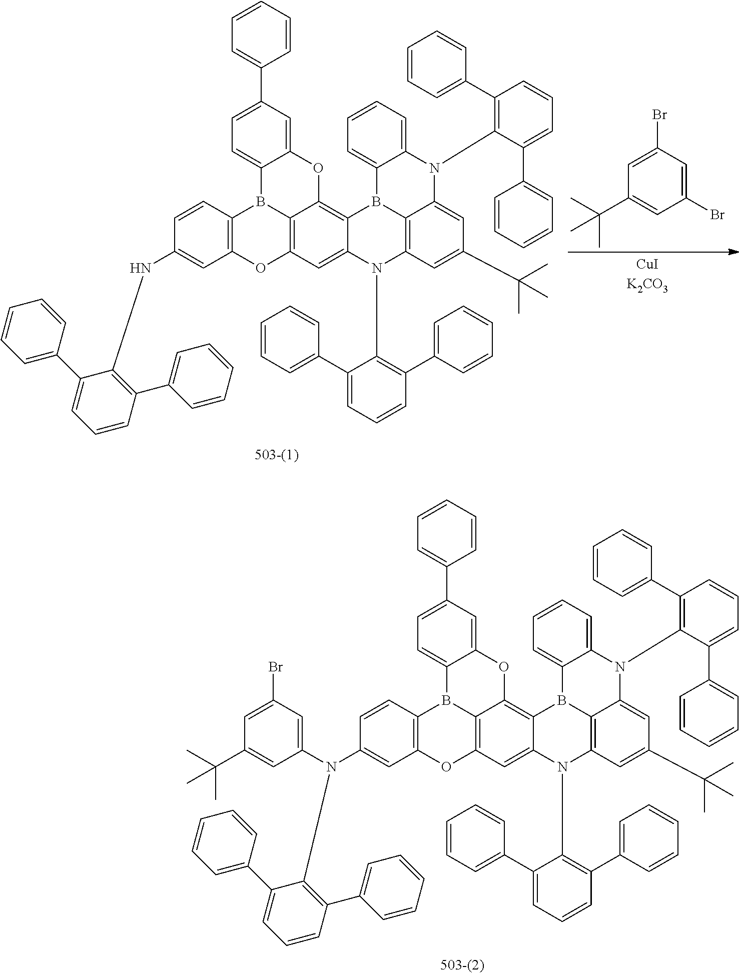

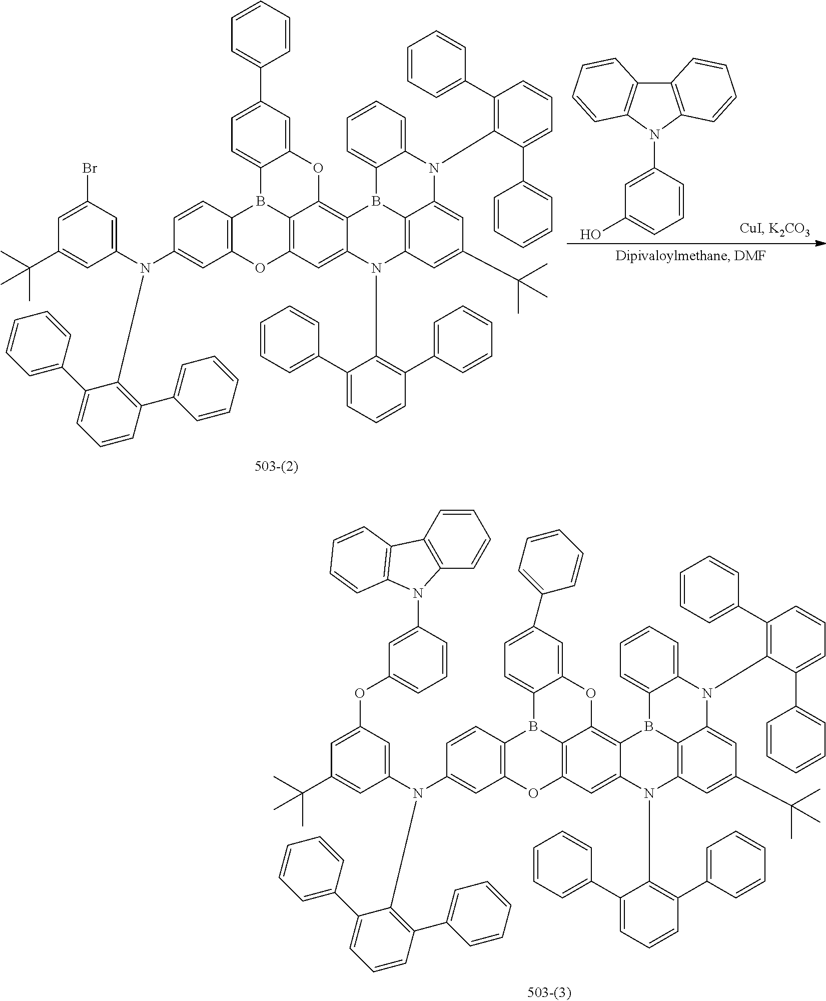

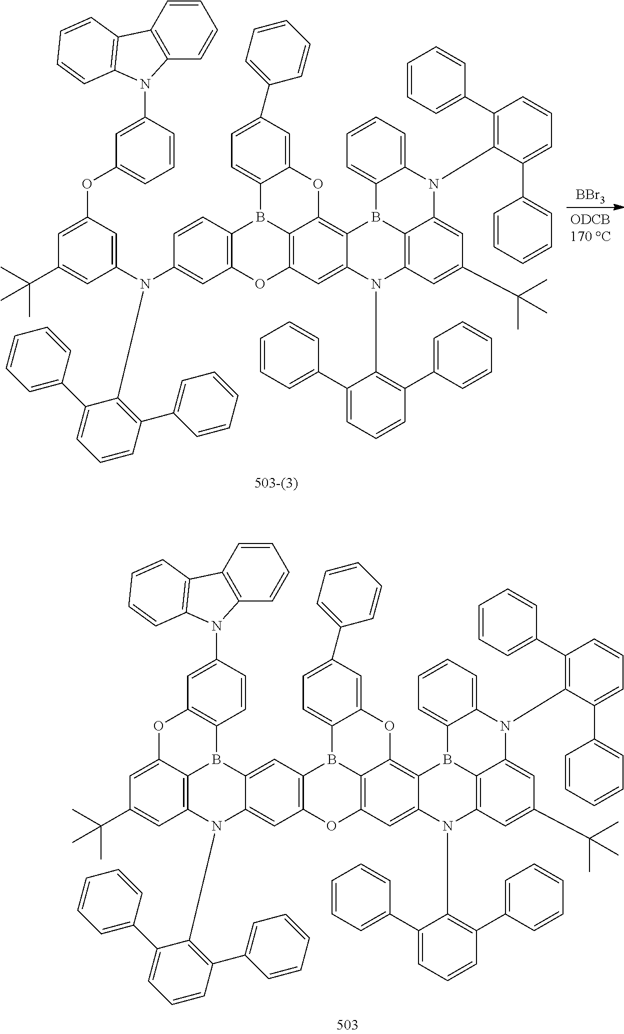

### Synthesis of Intermediate 503-(1)

In an Ar atmosphere, Intermediate 398-(9) (2.06 g, 1.83 mmol), [1,1′:3′,1″-terphenyl]-2′-amine (0.54 g, 2.19 mmol), Pd(dba)₂ (0.11 g, 0.18 mmol), P(tBu)₃·HBF4 (0.11 g, 0.37 mmol), and tBuONa (0.4 g, 4.2 mmol) were added to toluene (9 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 503-(1) (1.94 g, yield: 82%). As measured by FAB MS, Intermediate 503-(1) had a molecular weight of 1292.

### Synthesis of Intermediate 503-(2)

Intermediate 503-(1) (1.87 g, 1.45 mmol), 1,3-dibromo-5-(tert-butyl)benzene (3.38 g, 11.58 mmol), CuI (0.69 g, 3.62 mmol), and K₂CO₃ (8.71 g, 21.71 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 503-(2) (1.89 g, yield: 87%). As measured by FAB MS, Intermediate 503-(2) had a molecular weight of 1503.

### Synthesis of Intermediate 503-(3)

Intermediate 503-(2) (1.78 g, 1.18 mmol), 3-(9H-carbazol-9-yl)phenol (0.31 g, 1.18 mmol), CuI (0.25 g, 1.3 mmol), K₂CO₃ (0.65 g, 4.74 mmol), and dipivaloylmethane (2.48 g, 0.01 mmol) were added to DMF (24 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 503-(3) (1.43 g, yield: 72%). As measured by FAB MS, Intermediate 503-(3) had a molecular weight of 1682.

### Synthesis of Compound 503

In an Ar atmosphere, Intermediate 503-(3) (1.21 g, 0.72 mmol) was dissolved in ODCB (7 mL), BBr₃ (0.72 g, 2.88 mmol) was added, and the mixture was heated and stirred at 170 °C for 10 hours. The reaction solution was cooled to room temperature, DIPEA (1.11 g, 8.63 mmol) was added, and water was added, and then the mixture was subjected to celite filtering and liquid separation to concentrate an organic layer. The concentrated organic layer was purified through silica gel column chromatography to obtain Compound 503 (0.57 g, yield: 47%). The FAB MS measurement shows that Compound 503 had a molecular weight of 1689. Compound 503 was subjected to sublimation purification (380 °C, 2.7×10−3 Pa) and used to prepare a light emitting element.

### (3) Synthesis of Fused Polycyclic Compound 839

Fused polycyclic Compound 839 according to one or more embodiments may be synthesized through, for example, a process of Reaction Scheme 3.

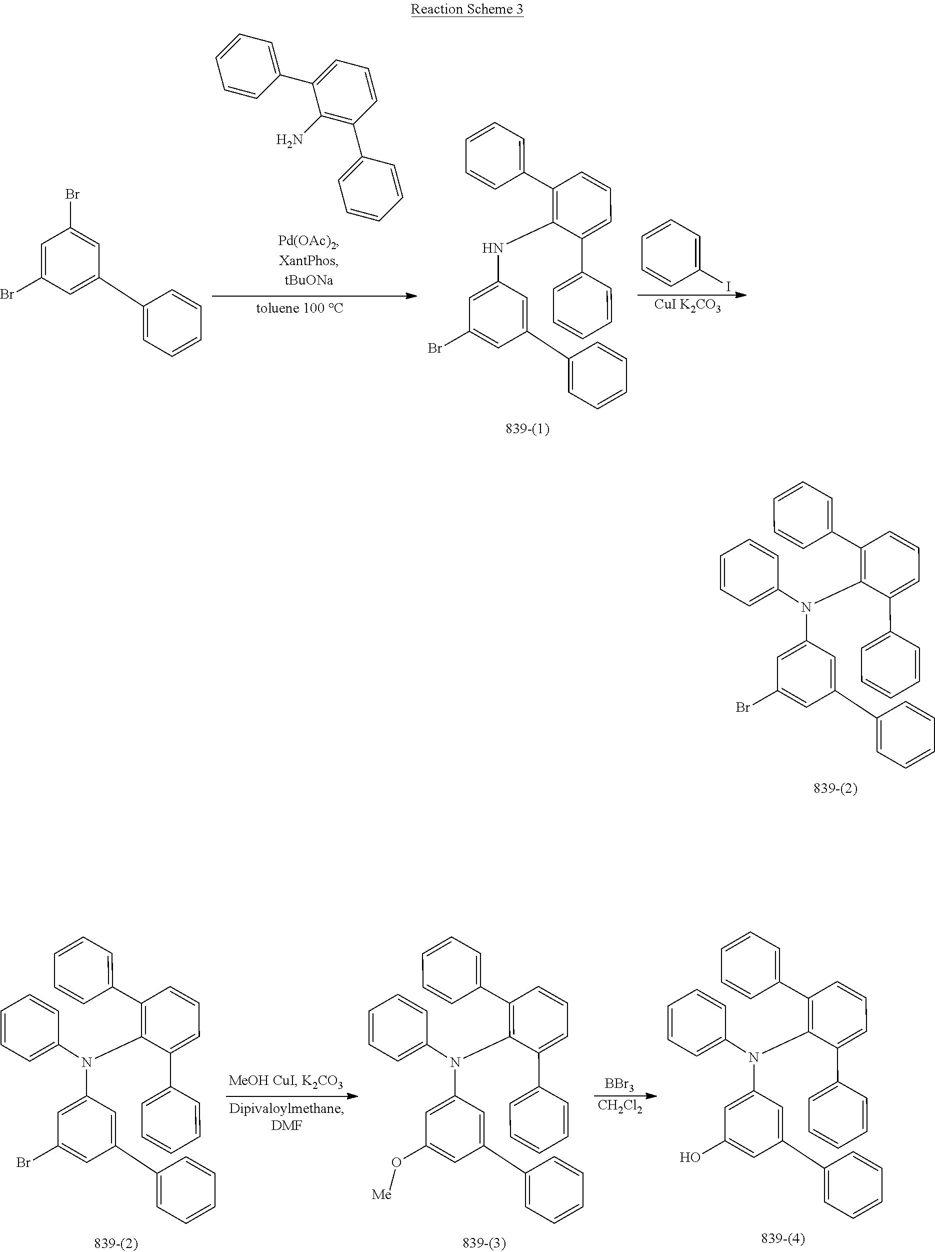

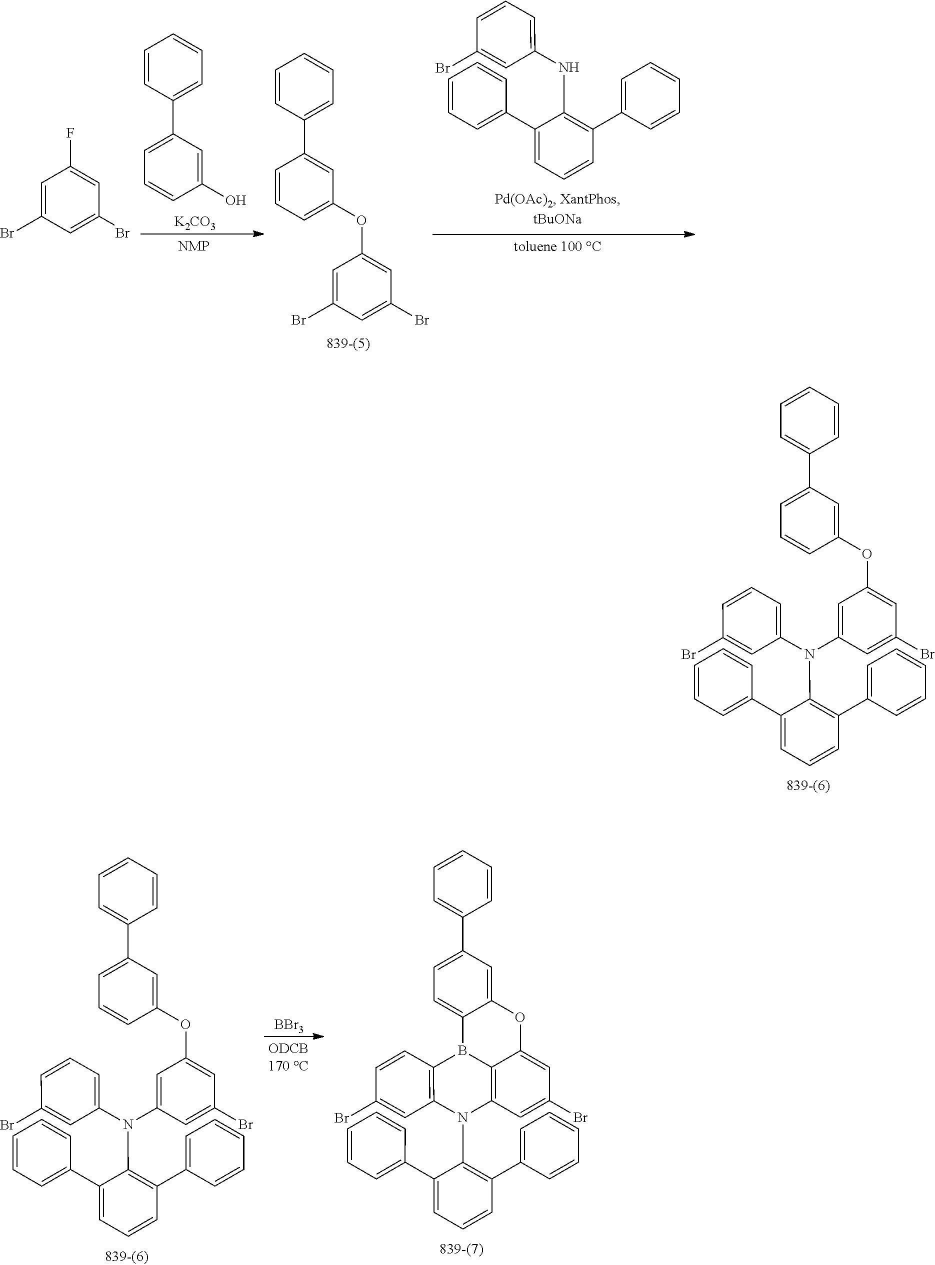

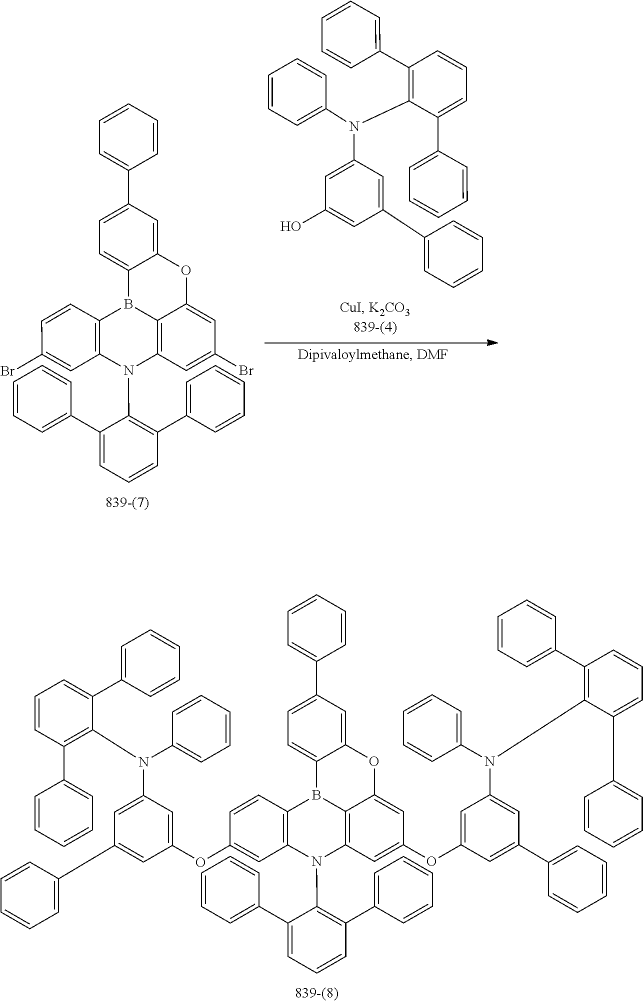 [SMILES: Brc1ccc2c(c1)N(c1c(-c3ccccc3)cccc1-c1ccccc1)c1cc(Br)cc3c1B2c1ccc(-c2ccccc2)cc1O3 ; Oc1cc(-c2ccccc2)cc(N(c2ccccc2)c2c(-c3ccccc3)cccc2-c2ccccc2)c1 ; c1ccc(-c2cc(Oc3ccc4c(c3)N(c3c(-c5ccccc5)cccc3-c3ccccc3)c3cc(Oc5cc(-c6ccccc6)cc(N(c6ccccc6)c6c(-c7ccccc7)cccc6-c6ccccc6)c5)cc5c3B4c3ccc(-c4ccccc4)cc3O5)cc(N(c3ccccc3)c3c(-c4ccccc4)cccc3-c3ccccc3)c2)cc1]

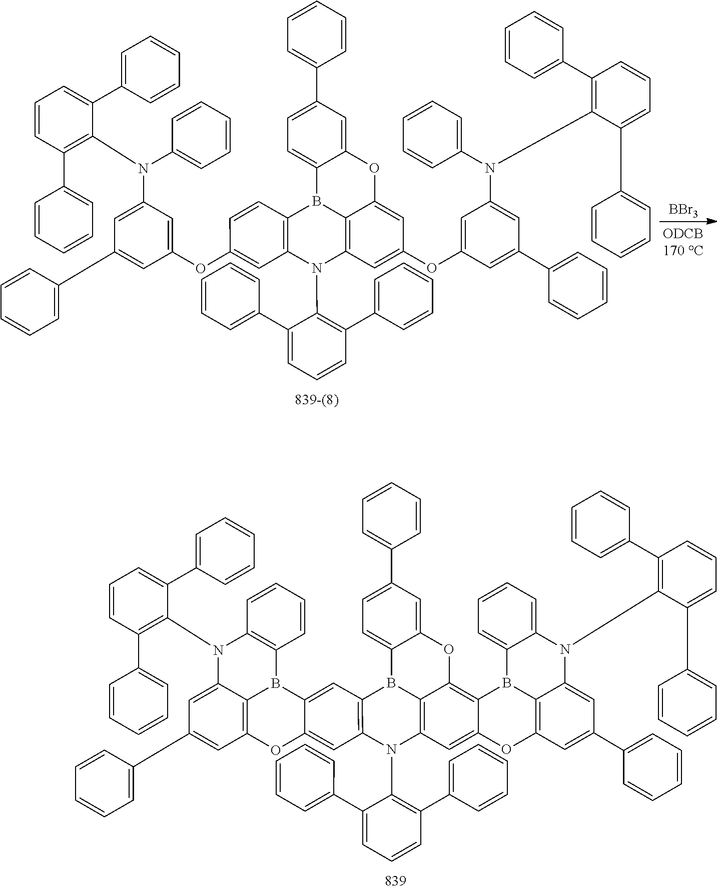

### Synthesis of Intermediate 839-(1)

In an Ar atmosphere, 3,5-dibromo-1,1′-biphenyl (12.04 g, 38.59 mmol), [1,1′:3′,1″-terphenyl]-2′-amine (9.47 g, 38.59 mmol), Pd(OAc)₂ (0.26 g, 1.16 mmol), XantPhos (1.34 g, 2.32 mmol), and tBuONa (4.45 g, 46.31 mmol) were added to toluene (192 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 839-(1) (16.18 g, yield: 88%). As measured by FAB MS, Intermediate 839-(1) had a molecular weight of 476.

### Synthesis of Intermediate 839-(2)

Intermediate 839-(1) (12.33 g, 25.88 mmol), iodobenzene (42.24 g, 207.04 mmol), CuI (12.32 g, 64.7 mmol), and K₂CO₃ (53.65 g, 388.21 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 839-(2) (11.15 g, yield: 78%). As measured by FAB MS, Intermediate 839-(2) had a molecular weight of 553.

### Synthesis of Intermediate 839-(3)

Intermediate 839-(2) (10.55 g, 19.09 mmol), MeOH (methanol, 1.84 g, 57.28 mmol), CuI (4.00 g, 21 mmol), K₂CO₃ (10.56 g, 76.38 mmol), and dipivaloylmethane (40 g, 0.22 mmol) were added to DMF (400 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 839-(3) (6.25 g, yield: 65%). As measured by FAB MS, Intermediate 839-(3) had a molecular weight of 504.

### Synthesis of Intermediate 839-(4)

In an Ar atmosphere, Intermediate 839-(3) (6.13 g, 12.17 mmol) was dissolved in CH₂Cl₂ (dichloromethane, 122 mL), BBr₃ (7.62 g, 30.43 mmol) was added, and the mixture was stirred at 0 °C for 24 hours. The reaction solution was added to ice water (307 mL), and the mixture was stirred for 1 hour and subjected to liquid separation to concentrate an organic layer. The concentrated organic layer was purified through silica gel column chromatography to obtain Intermediate 839-(4) (3.28 g, yield: 55%). As measured by FAB MS, Intermediate 839-(4) had a molecular weight of 490.

### Synthesis of Intermediate 839-(5)

In an Ar atmosphere, NMP (150 mL) was added to 1,3-dibromo-5-fluorobenzene (15.01 g, 59.12 mmol), [1,1′-biphenyl]-3-ol (10.06 g, 59.12 mmol), and K₂CO₃ (36.77 g, 266.03 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 839-(5) (18.87 g, yield: 79%). As measured by FAB MS, Intermediate 839-(5) had a molecular weight of 404.

### Synthesis of Intermediate 839-(6)

In an Ar atmosphere, Intermediate 839-(5) (18.03 g, 44.62 mmol), N-(3-bromophenyl)-[1,1′:3′,1″-terphenyl]-2′-amine (10.95 g, 44.62 mmol), Pd(OAc)₂ (0.3 g, 1.34 mmol), XantPhos (1.55 g, 2.68 mmol), and tBuONa (5.15 g, 53.54 mmol) were added to toluene (223 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 839-(6) (27.44 g, yield: 85%). As measured by FAB MS, Intermediate 839-(6) had a molecular weight of 724.

### Synthesis of Intermediate 839-(7)

In an Ar atmosphere, Intermediate 839-(6) (14.02 g, 19.38 mmol) was dissolved in ODCB (194 mL), BBr₃ (19.42 g, 77.51 mmol) was added, and the mixture was heated and stirred at 170 °C for 10 hours. The reaction solution was cooled to room temperature, N,N-diisopropylethylamine (DIPEA, 30 g, 232.53 mmol) was added, and water was added, and then the mixture was subjected to celite filtering and liquid separation to concentrate an organic layer. The concentrated organic layer was purified through silica gel column chromatography to obtain Intermediate 839-(7) (4.68 g, yield: 33%). As measured by FAB MS, Intermediate 839-(7) had a molecular weight of 731.

### Synthesis of Intermediate 839-(8)

Intermediate 839-(7) (2.01 g, 2.75 mmol), Intermediate 839-(4) (2.96 g, 6.05 mmol), CuI (0.58 g, 3.02 mmol), K₂CO₃ (1.52 g, 10.99 mmol), and dipivaloylmethane (5.76 g, 0.03 mmol) were added to DMF (57 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 839-(8) (2.89 g, yield: 68%). As measured by FAB MS, Intermediate 839-(8) had a molecular weight of 1549.

### Synthesis of Compound 839

In an Ar atmosphere, Intermediate 839-(8) (2.55 g, 1.65 mmol) was dissolved in ODCB (16 mL), BBr₃ (2.47 g, 9.88 mmol) was added, and the mixture was heated and stirred at 170 °C for 10 hours. The reaction solution was cooled to room temperature, DIPEA (2.55 g, 19.76 mmol) was added, and water was added, and then the mixture was subjected to celite filtering and liquid separation to concentrate an organic layer. The concentrated organic layer was purified through silica gel column chromatography to obtain Compound 839 (1.06 g, yield: 41%). The FAB MS measurement shows that Compound 839 had a molecular weight of 1564. Compound 839 was subjected to sublimation purification (370 °C, 2.2×10⁻³ Pa) and used to prepare a light emitting element.

### (4) Synthesis of Fused Polycyclic Compound 1043

Fused polycyclic Compound 1043 according to one or more embodiments may be synthesized through, for example, a process of Reaction Scheme 4.

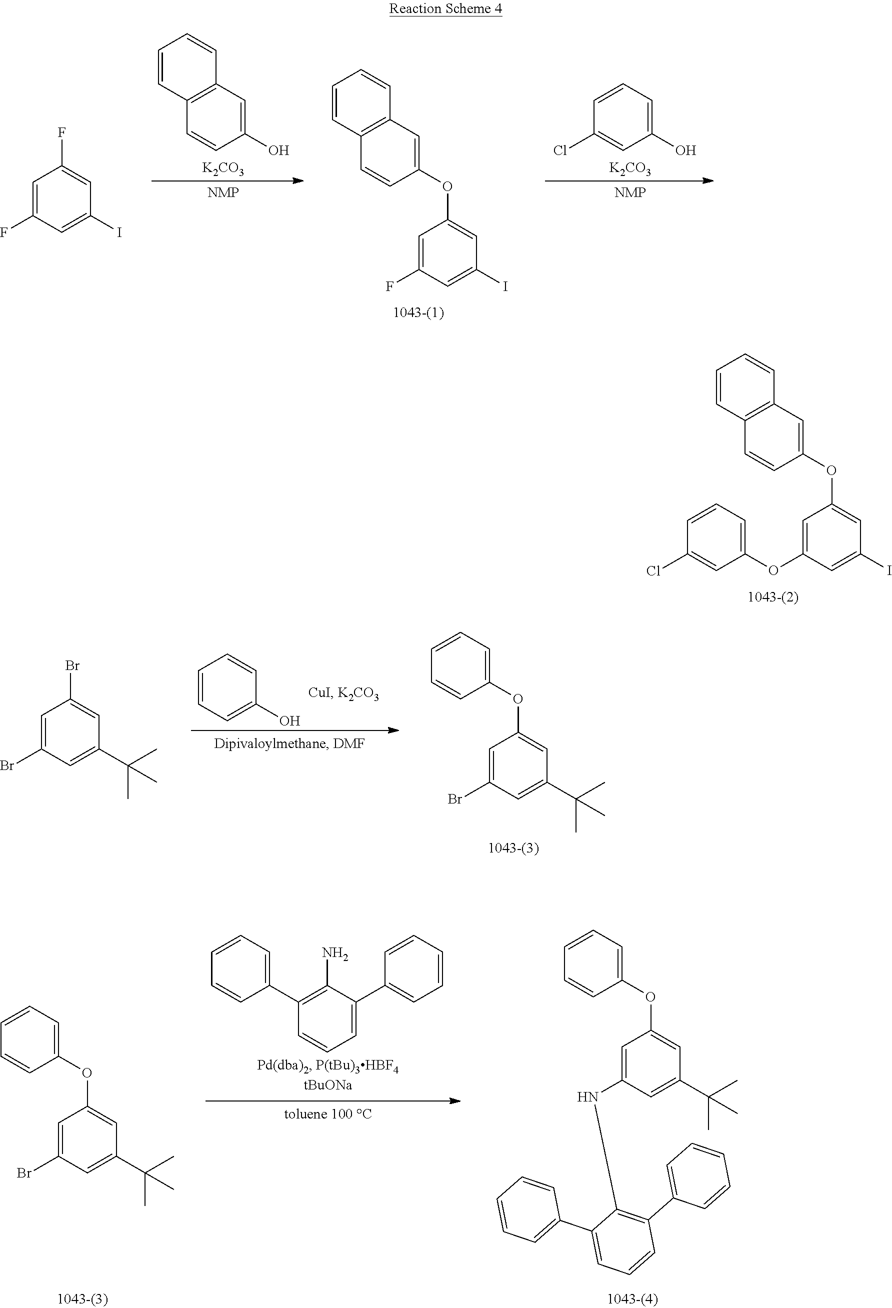

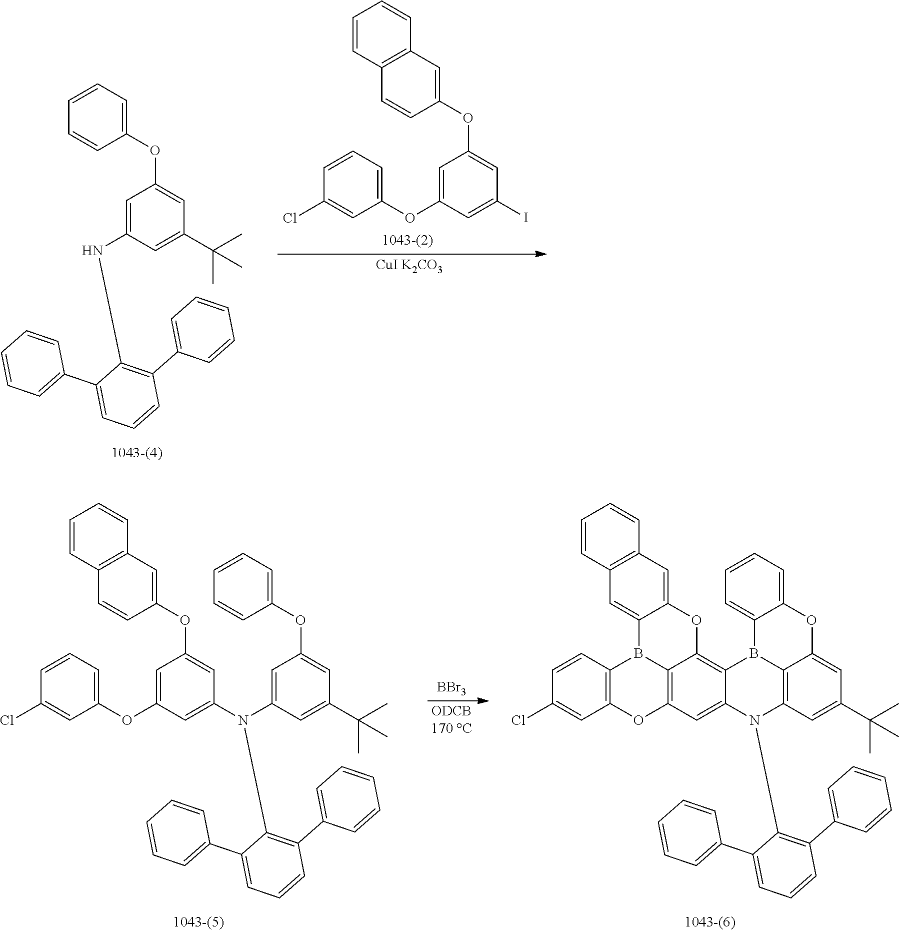

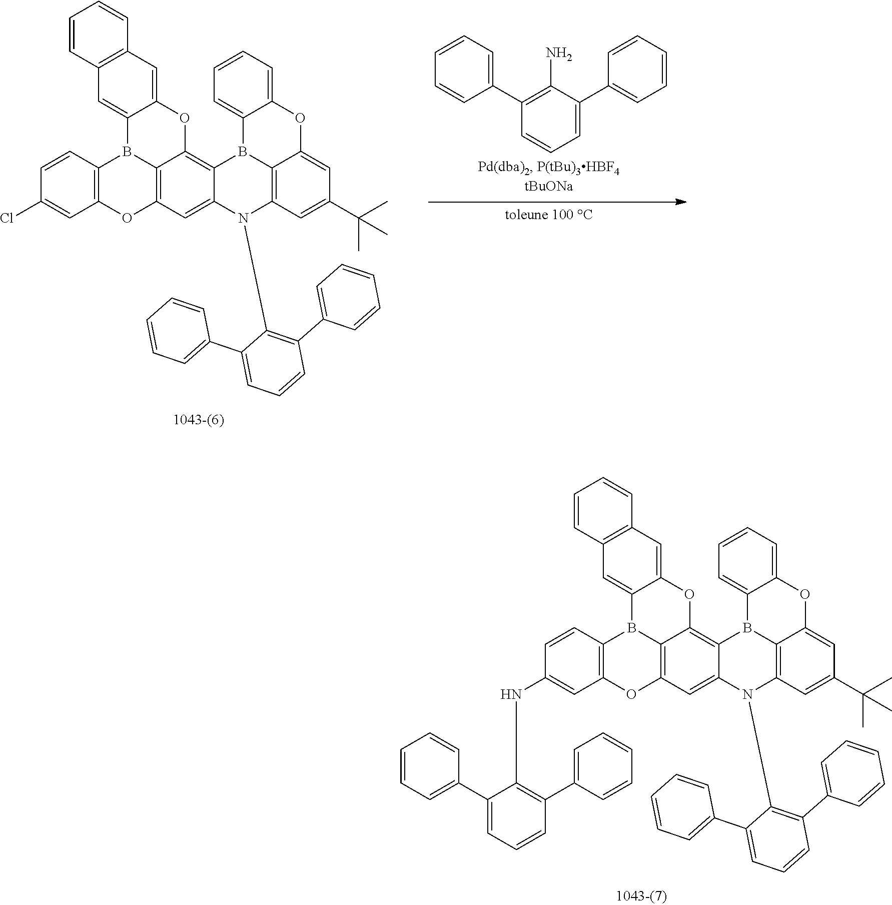 [SMILES: CC(C)(C)c1cc2c3c(c1)N(c1c(-c4ccccc4)cccc1-c1ccccc1)c1cc4c5c(c1B3c1ccccc1O2)Oc1cc2ccccc2cc1B5c1ccc(Cl)cc1O4 ; Nc1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc2ccccc2cc1B5c1ccc(Nc2c(-c3ccccc3)cccc2-c2ccccc2)cc1O4]

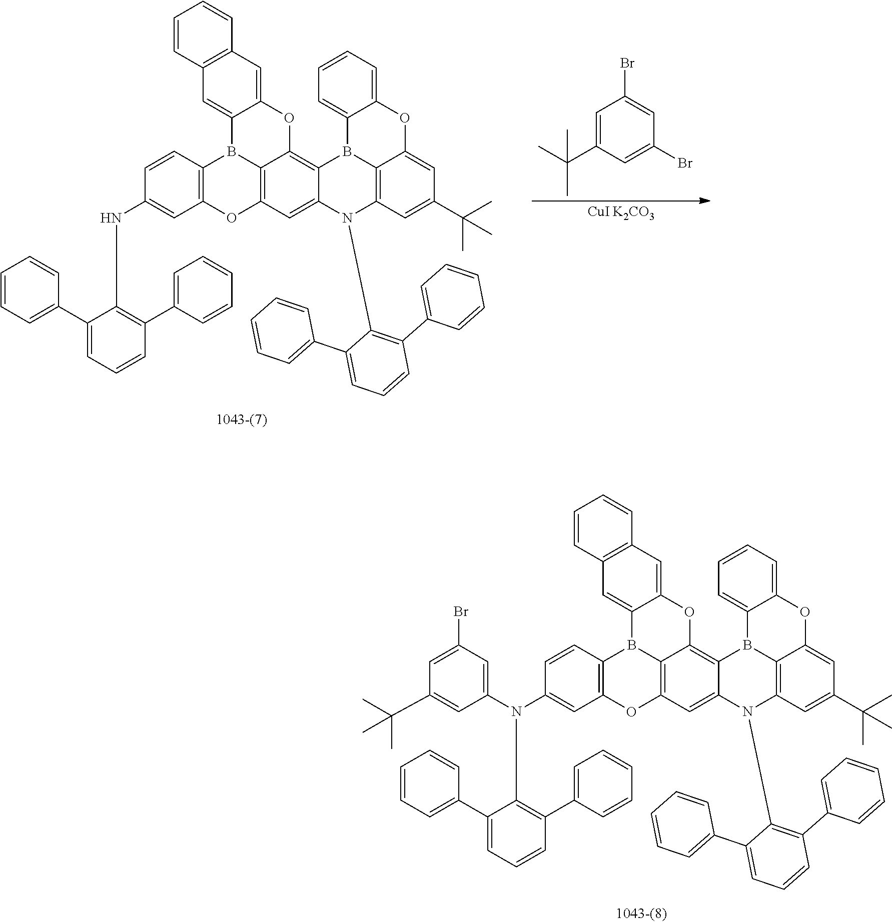

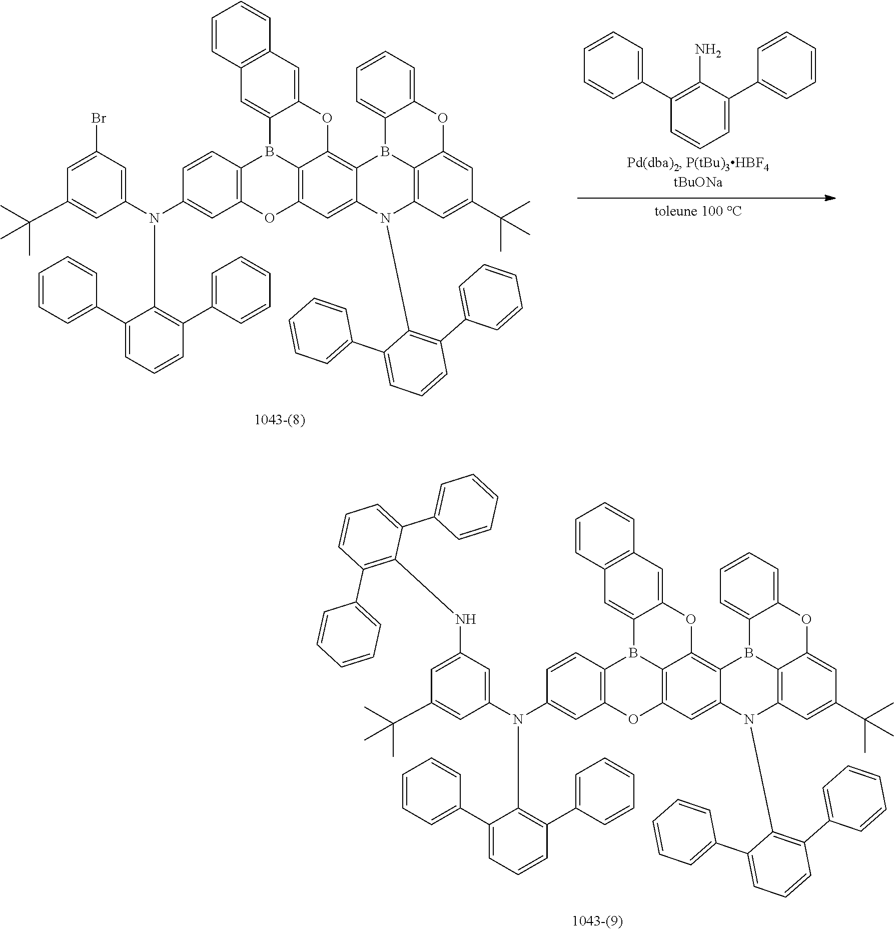 [SMILES: CC(C)(C)c1cc(Br)cc(N(c2ccc3c(c2)Oc2cc4c(c5c2B3c2cc3ccccc3cc2O5)B2c3ccccc3Oc3cc(C(C)(C)C)cc(c32)N4c2c(-c3ccccc3)cccc2-c2ccccc2)c2c(-c3ccccc3)cccc2-c2ccccc2)c1 ; Nc1c(-c2ccccc2)cccc1-c1ccccc1 ; CC(C)(C)c1cc(Nc2c(-c3ccccc3)cccc2-c2ccccc2)cc(N(c2ccc3c(c2)Oc2cc4c(c5c2B3c2cc3ccccc3cc2O5)B2c3ccccc3Oc3cc(C(C)(C)C)cc(c32)N4c2c(-c3ccccc3)cccc2-c2ccccc2)c2c(-c3ccccc3)cccc2-c2ccccc2)c1]

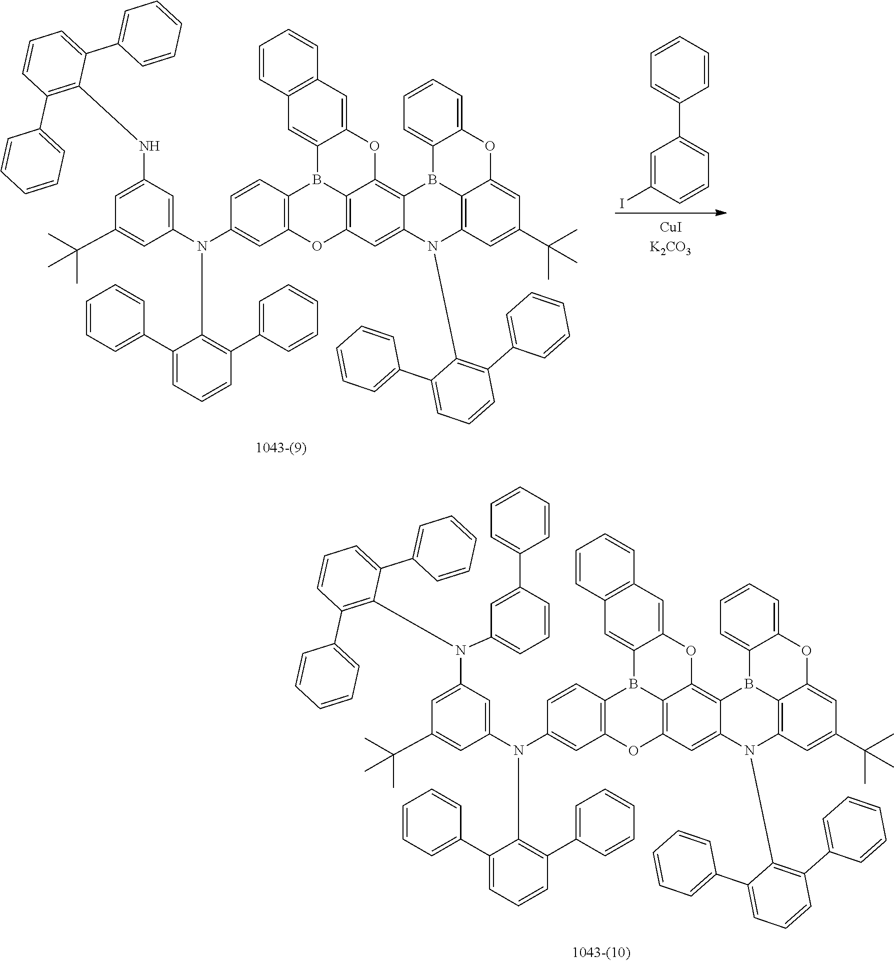 [SMILES: CC(C)(C)c1cc(Nc2c(-c3ccccc3)cccc2-c2ccccc2)cc(N(c2ccc3c(c2)Oc2cc4c(c5c2B3c2cc3ccccc3cc2O5)B2c3ccccc3Oc3cc(C(C)(C)C)cc(c32)N4c2c(-c3ccccc3)cccc2-c2ccccc2)c2c(-c3ccccc3)cccc2-c2ccccc2)c1 ; Ic1cccc(-c2ccccc2)c1 ; CC(C)(C)c1cc(N(c2cccc(-c3ccccc3)c2)c2c(-c3ccccc3)cccc2-c2ccccc2)cc(N(c2ccc3c(c2)Oc2cc4c(c5c2B3c2cc3ccccc3cc2O5)B2c3ccccc3Oc3cc(C(C)(C)C)cc(c32)N4c2c(-c3ccccc3)cccc2-c2ccccc2)c2c(-c3ccccc3)cccc2-c2ccccc2)c1]

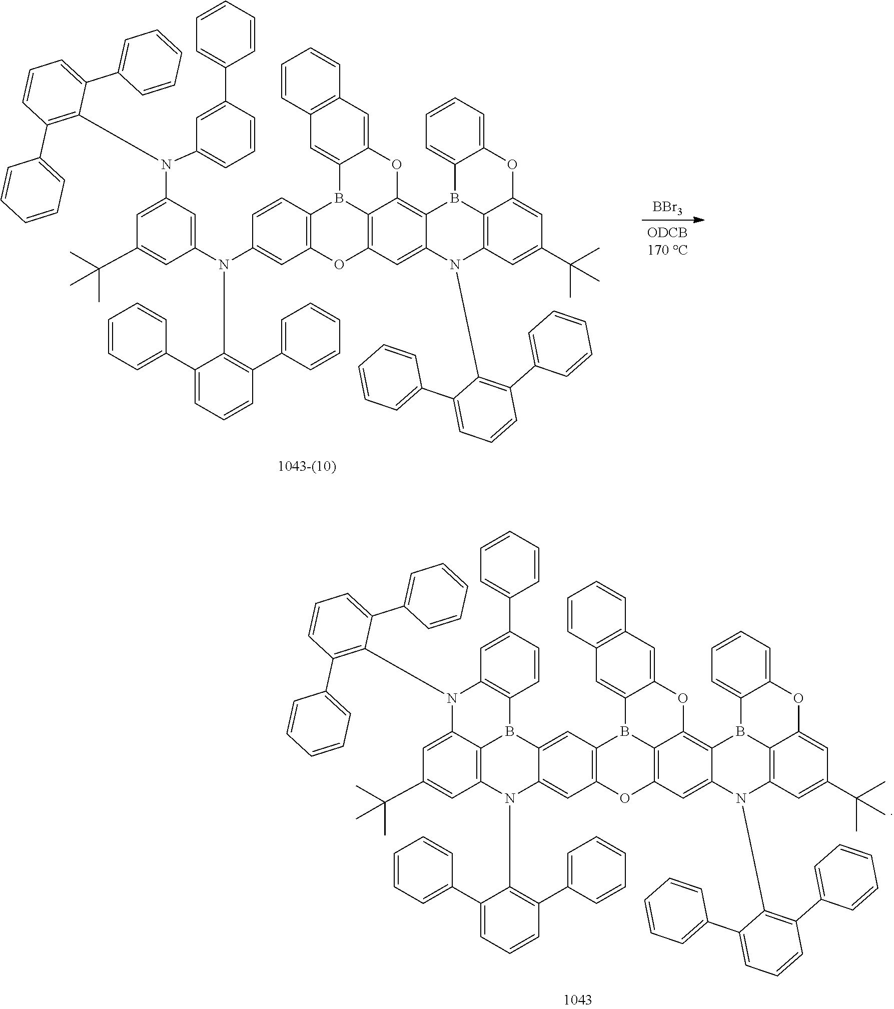 [SMILES: CC(C)(C)c1cc(N(c2cccc(-c3ccccc3)c2)c2c(-c3ccccc3)cccc2-c2ccccc2)cc(N(c2ccc3c(c2)Oc2cc4c(c5c2B3c2cc3ccccc3cc2O5)B2c3ccccc3Oc3cc(C(C)(C)C)cc(c32)N4c2c(-c3ccccc3)cccc2-c2ccccc2)c2c(-c3ccccc3)cccc2-c2ccccc2)c1 ; "BBr3" ; CC(C)(C)c1cc2c3c(c1)N(c1c(-c4ccccc4)cccc1-c1ccccc1)c1cc4c5c(c1B3c1ccccc1O2)Oc1cc2ccccc2cc1B5c1cc2c(cc1O4)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1]

### Synthesis of Intermediate 1043-(1)

In an Ar atmosphere, NMP (252 mL) was added to 1,3-difluoro-5-iodobenzene (25.21 g, 105.05 mmol), naphthalen-2-ol (15.14 g, 105.05 mmol), and K₂CO₃ (65.33 g, 472.71 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(1) (28.69 g, yield: 75%). As measured by FAB MS, Intermediate 1043-(1) had a molecular weight of 364.

### Synthesis of Intermediate 1043-(2)

In an Ar atmosphere, NMP (275 mL) was added to Intermediate 1043-(1) (27.58 g, 75.74 mmol), 3-chlorophenol (9.74 g, 75.74 mmol), and K₂CO₃ (47.1 g, 340.81 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(2) (29.36 g, yield: 82%). As measured by FAB MS, Intermediate 1043-(2) had a molecular weight of 473.

### Synthesis of Intermediate 1043-(3)

1,3-dibromo-5-(tert-butyl)benzene (25.02 g, 85.68 mmol), phenol (8.06 g, 85.68 mmol), CuI (17.95 g, 94.25 mmol), K₂CO₃ (47.37 g, 342.73 mmol), and dipivaloylmethane (179.5 g, 0.97 mmol) were added to DMF (1794 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(3) (13.60 g, yield: 52%). As measured by FAB MS, Intermediate 1043-(3) had a molecular weight of 305.

### Synthesis of Intermediate 1043-(4)

In an Ar atmosphere, Intermediate 1043-(3) (12.98 g, 42.53 mmol), [1,1′:3′,1″-terphenyl]-2′-amine (12.52 g, 51.03 mmol), Pd(dba)₂ (2.45 g, 4.25 mmol), P(tBu)₃·HBF4 (2.47 g, 8.51 mmol), and tBuONa (9.4 g, 97.81 mmol) were added to toluene (212 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1043-(4) (18.97 g, yield: 95%). As measured by FAB MS, Intermediate 1043-(4) had a molecular weight of 470.

### Synthesis of Intermediate 1043-(5)

Intermediate 1043-(4) (5.36 g, 11.41 mmol), Intermediate 1043-(2) (26.98 g, 57.07 mmol), CuI (5.43 g, 28.53 mmol), and K₂CO₃ (23.66 g, 171.2 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(5) (6.41 g, yield: 69%). As measured by FAB MS, Intermediate 1043-(5) had a molecular weight of 814.

### Synthesis of Intermediate 1043-(6)

In an Ar atmosphere, Intermediate 1043-(5) (6.28 g, 7.71 mmol) was dissolved in ODCB (77 mL), BBr₃ (7.73 g, 30.84 mmol) was added, and the mixture was heated and stirred at 170 °C for 10 hours. The reaction solution was cooled to room temperature, DIPEA (11.94 g, 92.53 mmol) was added, and water was added, and then the mixture was subjected to celite filtering and liquid separation to concentrate an organic layer. The concentrated organic layer was purified through silica gel column chromatography to obtain Intermediate 1043-(6) (0.96 g, yield: 15%). As measured by FAB MS, Intermediate 1043-(6) had a molecular weight of 830.

### Synthesis of Intermediate 1043-(7)

In an Ar atmosphere, Intermediate 1043-(6) (0.93 g, 1.12 mmol), [1,1′:3′,1″-terphenyl]-2′-amine (0.33 g, 1.34 mmol), Pd(dba)₂ (0.06 g, 0.11 mmol), P(tBu)₃·HBF4 (0.07 g, 0.22 mmol), and tBuONa (0.25 g, 2.58 mmol) were added to toluene (5 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1043-(7) (1.07 g, yield: 92%). As measured by FAB MS, Intermediate 1043-(7) had a molecular weight of 1039.

### Synthesis of Intermediate 1043-(8)

Intermediate 1043-(7) (1.05 g, 1.01 mmol), 1,3-dibromo-5-(tert-butyl)benzene (2.36 g, 8.09 mmol), CuI (0.48 g, 2.53 mmol), and K₂CO₃ (2.1 g, 15.16 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(8) (0.93 g, yield: 74%). As measured by FAB MS, Intermediate 1043-(8) had a molecular weight of 1250.

### Synthesis of Intermediate 1043-(9)

In an Ar atmosphere, Intermediate 1043-(8) (0.91 g, 0.73 mmol), [1,1′:3′,1″-terphenyl]-2′-amine (0.21 g, 0.87 mmol), Pd(dba)₂ (0.04 g, 0.07 mmol), P(tBu)₃·HBF4 (0.04 g, 0.15 mmol), and tBuONa (0.16 g, 1.67 mmol) were added to toluene (3 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1043-(9) (0.98 g, yield: 95%). As measured by FAB MS, Intermediate 1043-(9) had a molecular weight of 1414.

### Synthesis of Intermediate 1043-(10)

Intermediate 1043-(9) (0.95 g, 0.67 mmol), 3-iodo-1,1′-biphenyl (1.51 g, 5.37 mmol), CuI (0.32 g, 1.68 mmol), and K₂CO₃ (1.39 g, 10.08 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1043-(10) (0.75 g, yield: 71%). As measured by FAB MS, Intermediate 1043-(10) had a molecular weight of 1567.

### Synthesis of Compound 1043

In an Ar atmosphere, Intermediate 1043-(10) (0.73 g, 0.47 mmol) was dissolved in ODCB (5 mL), BBr₃ (0.47 g, 1.86 mmol) was added, and the mixture was heated and stirred at 170 °C for 10 hours. The reaction solution was cooled to room temperature, DIPEA (0.72 g, 5.59 mmol) was added, and water was added, and then the mixture was subjected to celite filtering and liquid separation to concentrate an organic layer. The concentrated organic layer was purified through silica gel column chromatography to obtain Compound 1043 (0.30 g, yield: 41%). The FAB MS measurement shows that Compound 1043 had a molecular weight of 1574. The obtained Compound 1043 was subjected to sublimation purification (380 °C, 2.1×10−3 Pa) and used to prepare a light emitting element.

### (5) Synthesis of Fused Polycyclic Compound 1074

Fused polycyclic Compound 1074 according to one or more embodiments may be synthesized through, for example, a process of Reaction Scheme 5.

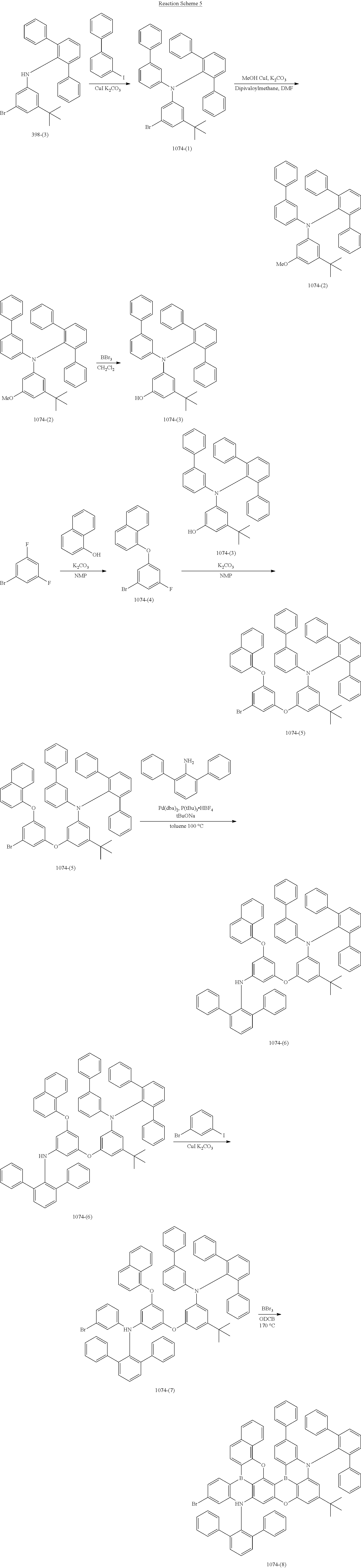

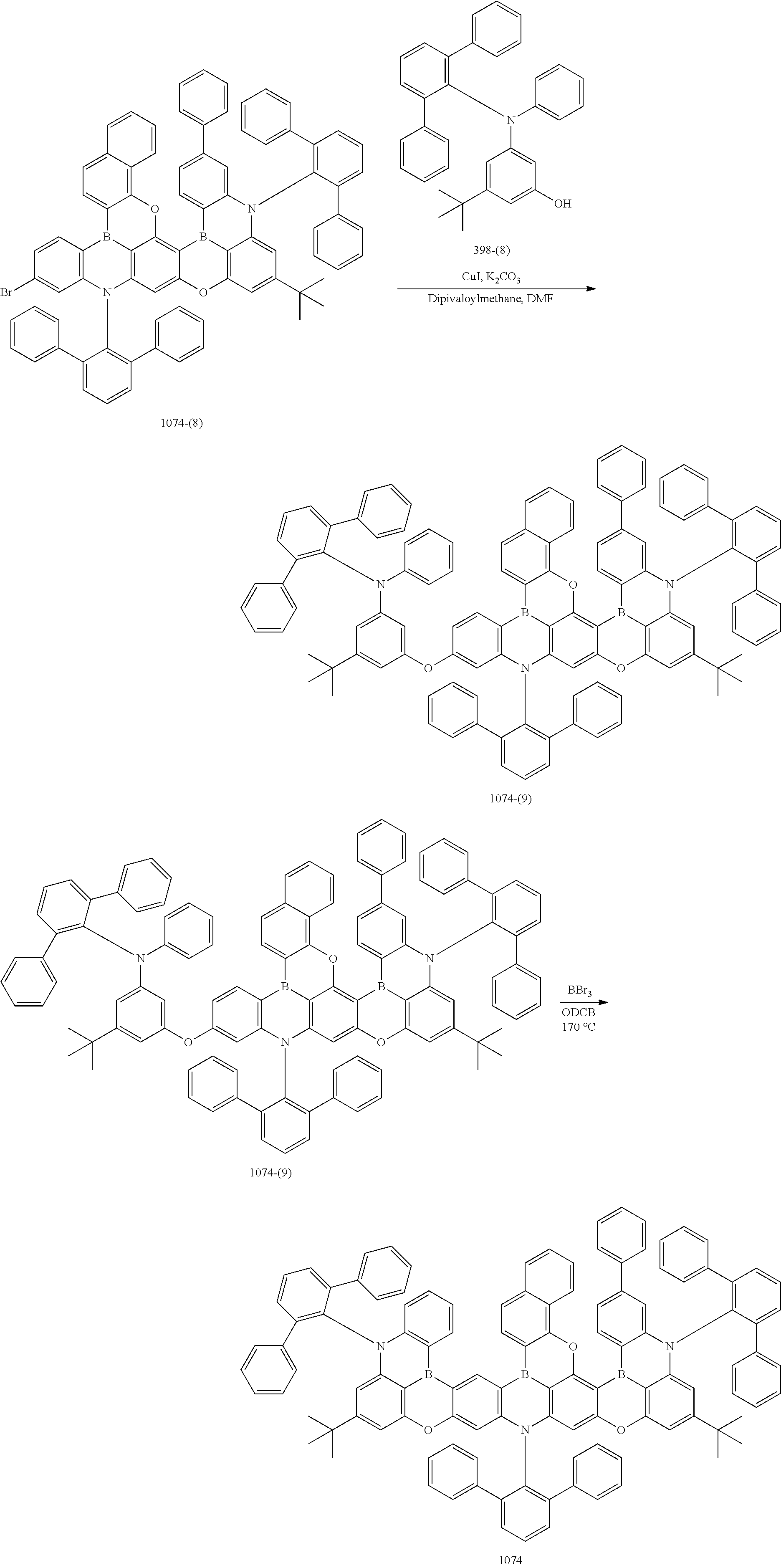

### Synthesis of Intermediate 1074-(1)

Intermediate 398-(3) (12.05 g, 26.4 mmol), 3-iodo-1,1′-biphenyl (43.09 g, 211.2 mmol), CuI (12.57 g, 66 mmol, and K₂CO₃ (54.73 g, 396.01 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(1) (11.89 g, yield: 74%). As measured by FAB MS, Intermediate 1074-(1) had a molecular weight of 609.

### Synthesis of Intermediate 1074-(2)

Intermediate 1074-(1) (11.55 g, 18.98 mmol), methanol (MeOH, 0.61 g, 18.98 mmol), Gui (3.98 g, 20.88 mmol), K₂CO₃ (10.49 g, 75.91 mmol), and dipivaloylmethane (39.76 g, 0.22 mmol) were added to DMF (397 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(2) (6.16 g, yield: 58%). As measured by FAB MS, Intermediate 1074-(2) had a molecular weight of 560.

### Synthesis of Intermediate 1074-(3)

In an Ar atmosphere, Intermediate 1074-(2) (5.98 g, 10.68 mmol) was dissolved in dichloromethane (CH₂Cl₂, 107 mL), BBr₃ (6.69 g, 26.71 mmol) was added, and the mixture was stirred at 0 °C for 24 hours. The reaction solution was added to ice water (299 mL), and the mixture was stirred for 1 hour and subjected to liquid separation to concentrate an organic layer. The concentrated organic layer was purified through silica gel column chromatography to obtain Intermediate 1074-(3) (3.56 g, yield: 61%). As measured by FAB MS, Intermediate 1074-(3) had a molecular weight of 546.

### Synthesis of Intermediate 1074-(4)

In an Ar atmosphere, NMP (120 mL) was added to 1-bromo-3,5-difluorobenzene (12.01 g, 62.23 mmol), naphthalen-1-ol (8.97 g, 62.23 mmol), and K₂CO₃ (38.7 g, 280.04 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(4) (15.79 g, yield: 80%). As measured by FAB MS, Intermediate 1074-(4) had a molecular weight of 317.

### Synthesis of Intermediate 1074-(5)

In an Ar atmosphere, NMP (153 mL) was added to Intermediate 1074-(4) (15.33 g, 48.34 mmol), Intermediate 1074-(3) (26.38 g, 48.34 mmol), and K₂CO₃ (30.06 g, 217.51 mmol), and the mixture was heated at constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(5) (34.22 g, yield: 84%). As measured by FAB MS, Intermediate 1074-(5) had a molecular weight of 843.

### Synthesis of Intermediate 1074-(6)

In an Ar atmosphere, Intermediate 1074-(5) (34.11 g, 40.47 mmol), [1,1′:3′,1″-terphenyl]-2′-amine (11.91 g, 48.56 mmol), Pd(dba)₂ (2.33 g, 4.05 mmol), P(tBu)₃·HBF4 (2.35 g, 8.09 mmol), and tBuONa (8.94 g, 93.08 mmol) were added to toluene (202 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1074-(6) (37.5 g, yield: 92%). As measured by FAB MS, Intermediate 1074-(6) had a molecular weight of 1007.

### Synthesis of Intermediate 1074-(7)

Intermediate 1074-(6) (37.22 g, 36.95 mmol), 1-bromo-3-iodobenzene (83.63 g, 295.61 mmol), CuI (17.59 g, 92.38 mmol), and K₂CO₃ (76.6 g, 554.26 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(7) (30.49 g, yield: 71%). As measured by FAB MS, Intermediate 1074-(7) had a molecular weight of 1162.

### Synthesis of Intermediate 1074-(8)

In an Ar atmosphere, Intermediate 1074-(7) (30.05 g, 25.85 mmol) was dissolved in ODCB (259 mL), BBr₃ (25.91 g, 103.42 mmol) was added, and the mixture was heated and stirred at 170 °C for 10 hours. The reaction solution was cooled to room temperature, DIPEA (40.02 g, 310.25 mmol) was added, and water was added, and then the mixture was subjected to celite filtering and liquid separation to concentrate an organic layer. The concentrated organic layer was purified through silica gel column chromatography to obtain Intermediate 1074-(8) (3.65 g, yield: 12%). As measured by FAB MS, Intermediate 1074-(8) had a molecular weight of 1178.

### Synthesis of Intermediate 1074-(9)

Intermediate 1074-(8) (3.44 g, 2.92 mmol), Intermediate 398-(8) (1.37 g, 2.92 mmol), CuI (0.61 g, 3.21 mmol), K₂CO₃ (1.61 g, 11.68 mmol), and dipivaloylmethane (6.12 g, 0.03 mmol) were added to DMF (61 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1074-(9) (2.33 g, yield: 51%). As measured by FAB MS, Intermediate 1074-(9) had a molecular weight of 1567.

### Synthesis of Compound 1074

In an Ar atmosphere, Intermediate 1074-(9) (2.11 g, 1.35 mmol) was dissolved in ODCB (13 mL), BBr₃ (1.35 g, 5.39 mmol) was added, and the mixture was heated and stirred at 170 °C for 10 hours. The reaction solution was cooled to room temperature, DIPEA (2.08 g, 16.16 mmol) was added, and water was added, and then the mixture was subjected to celite filtering and liquid separation to concentrate an organic layer. The concentrated organic layer was purified through silica gel column chromatography to obtain Compound 1074 (0.95 g, yield: 45%). The FAB MS measurement shows that Compound 1074 had a molecular weight of 1574. The obtained Compound 1074 was subjected to sublimation purification (370 °C, 2.8×10⁻³ Pa) and used to prepare a light emitting element.

### (6) Synthesis of Fused Polycyclic Compound 1117

Fused polycyclic Compound 1117 according to one or more embodiments may be synthesized through, for example, a process of Reaction Scheme 6.

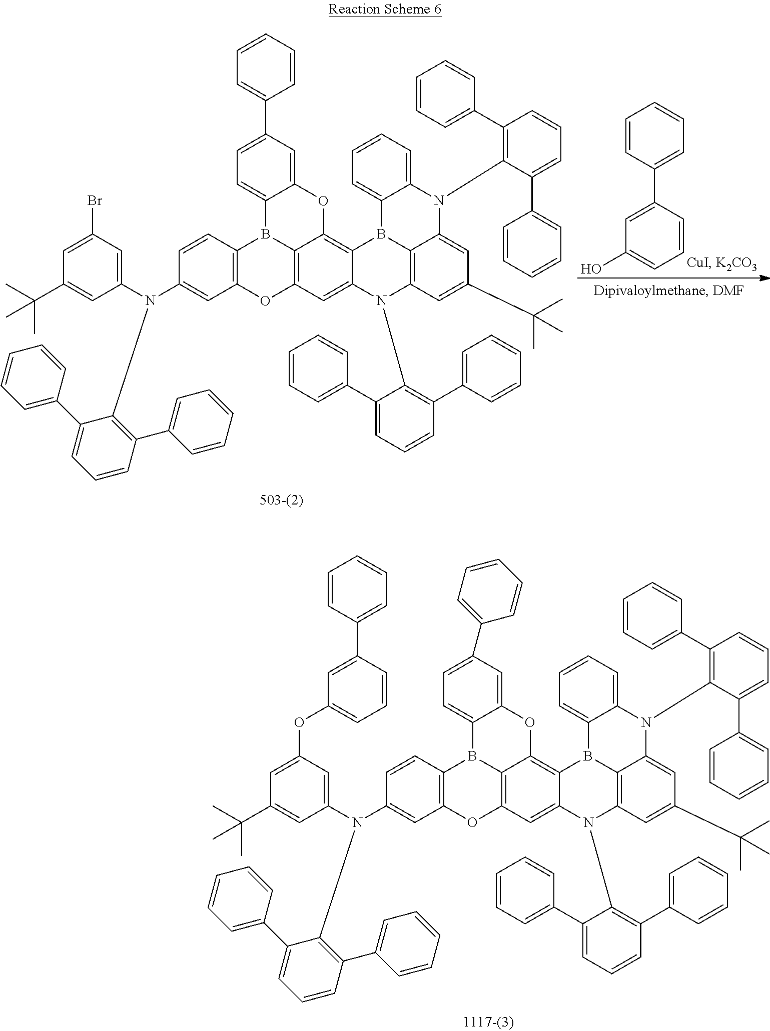

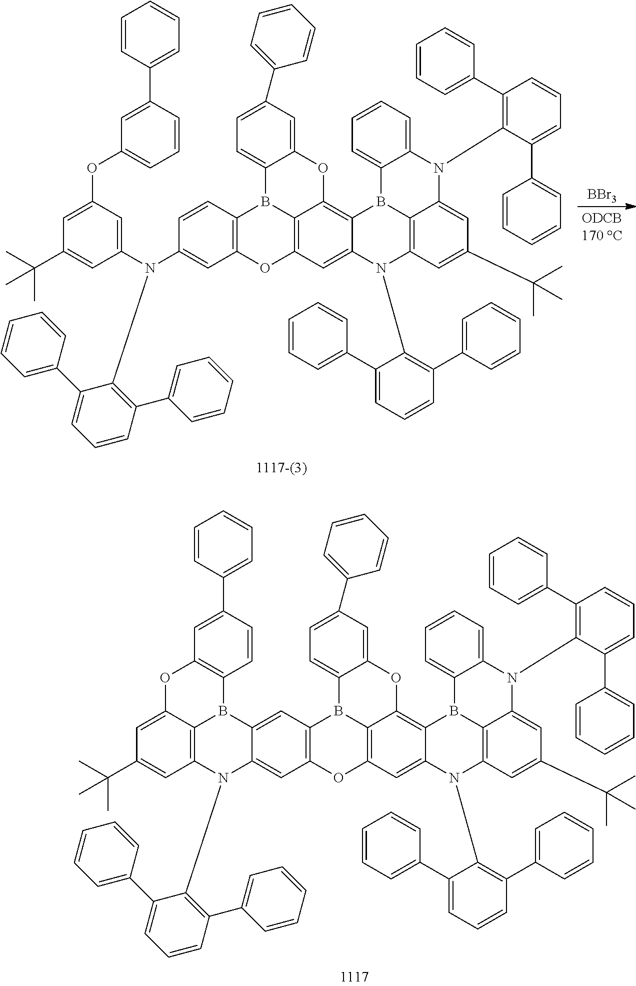

Intermediate 503-(2) (1.21 g, 0.8 mmol), [1,1′-biphenyl]-3-ol (0.14 g, 0.8 mmol), CuI (0.17 g, 0.89 mmol), K₂CO₃ (0.44 g, 3.22 mmol), and dipivaloylmethane (1.69 g, 0.01 mmol) were added to DMF (16 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1117-(3) (0.67 g, yield: 52%). As measured by FAB MS, Intermediate 1117-(3) had a molecular weight of 1593.

### Synthesis of Compound 1117

In an Ar atmosphere, Intermediate 1117-(3) (0.65 g, 0.41 mmol) was dissolved in ODCB (4 mL), BBr₃ (0.41 g, 1.63 mmol) was added, and the mixture was heated and stirred at 170 °C for 10 hours. The reaction solution was cooled to room temperature, DIPEA (0.63 g, 4.9 mmol) was added, and water was added, and then the mixture was subjected to celite filtering and liquid separation to concentrate an organic layer. The concentrated organic layer was purified through silica gel column chromatography to obtain Compound 1117 (0.29 g, yield: 45%). The FAB MS measurement shows that Compound 1117 had a molecular weight of 1600. The obtained Compound 1117 was subjected to sublimation purification (380 °C, 2.2×10⁻³ Pa) and used to prepare a light emitting element.

### (7) Synthesis of Fused Polycyclic Compound 1171

Fused polycyclic Compound 1171 according to one or more embodiments may be synthesized through, for example, a process of Reaction Scheme 7.

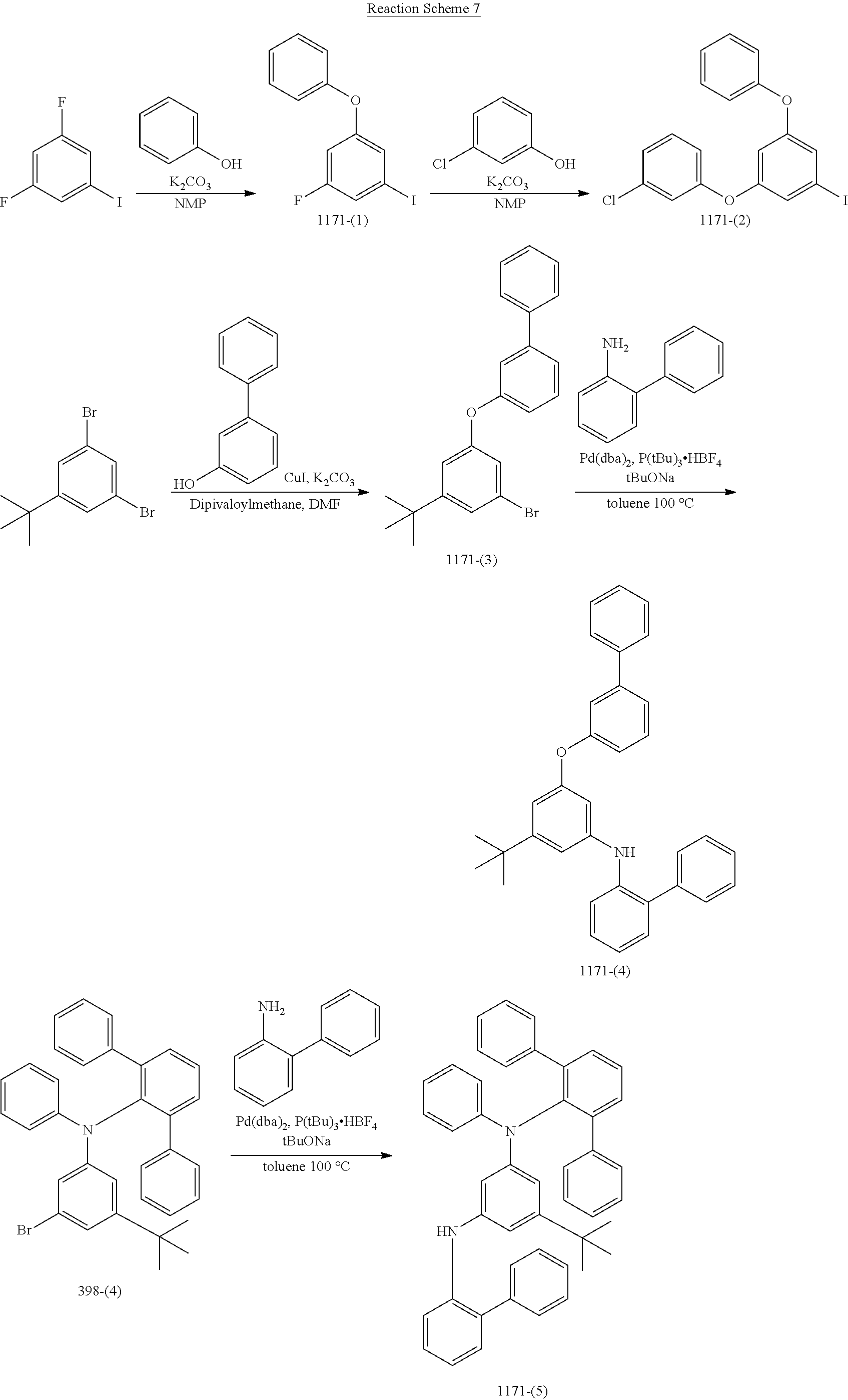

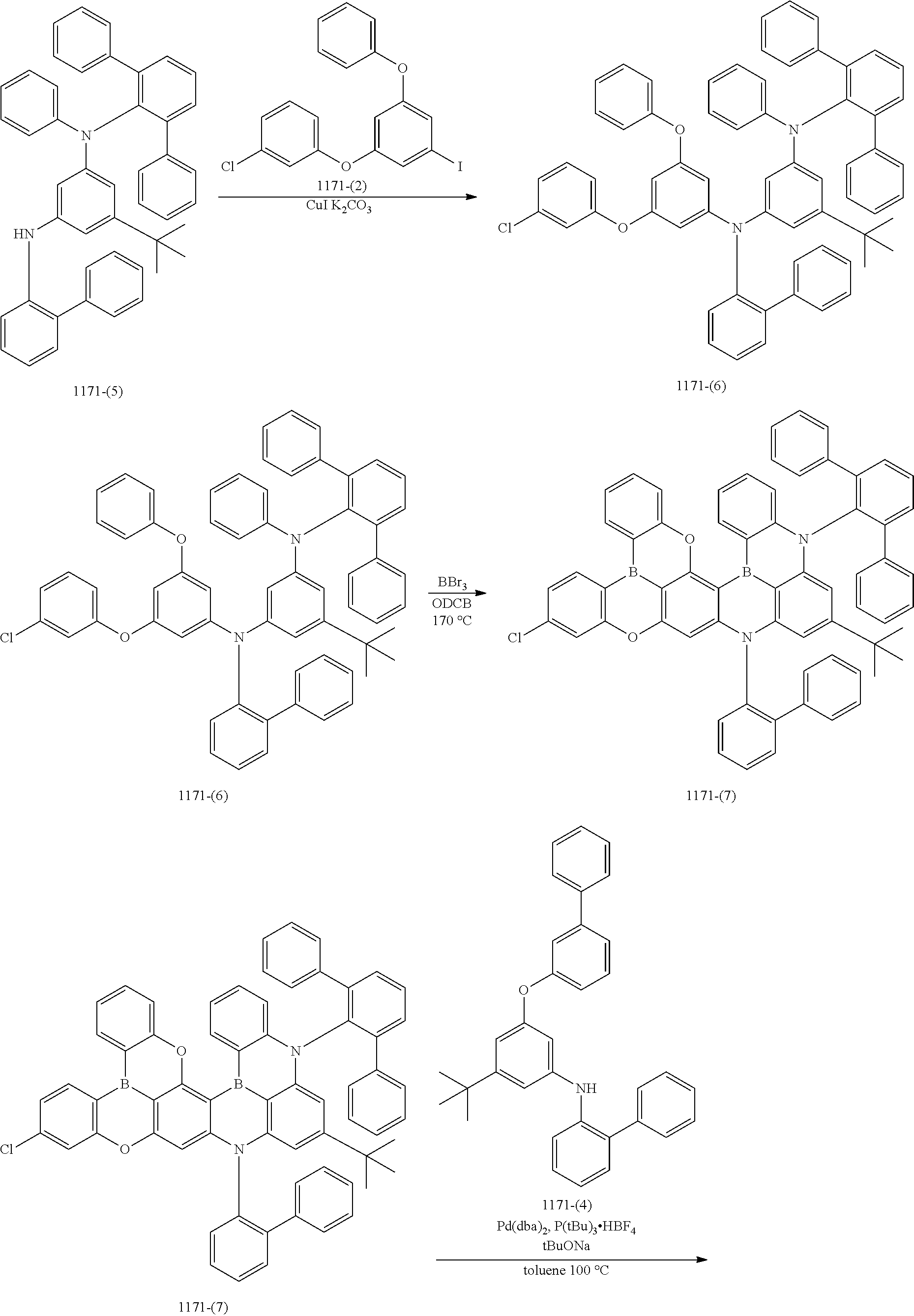

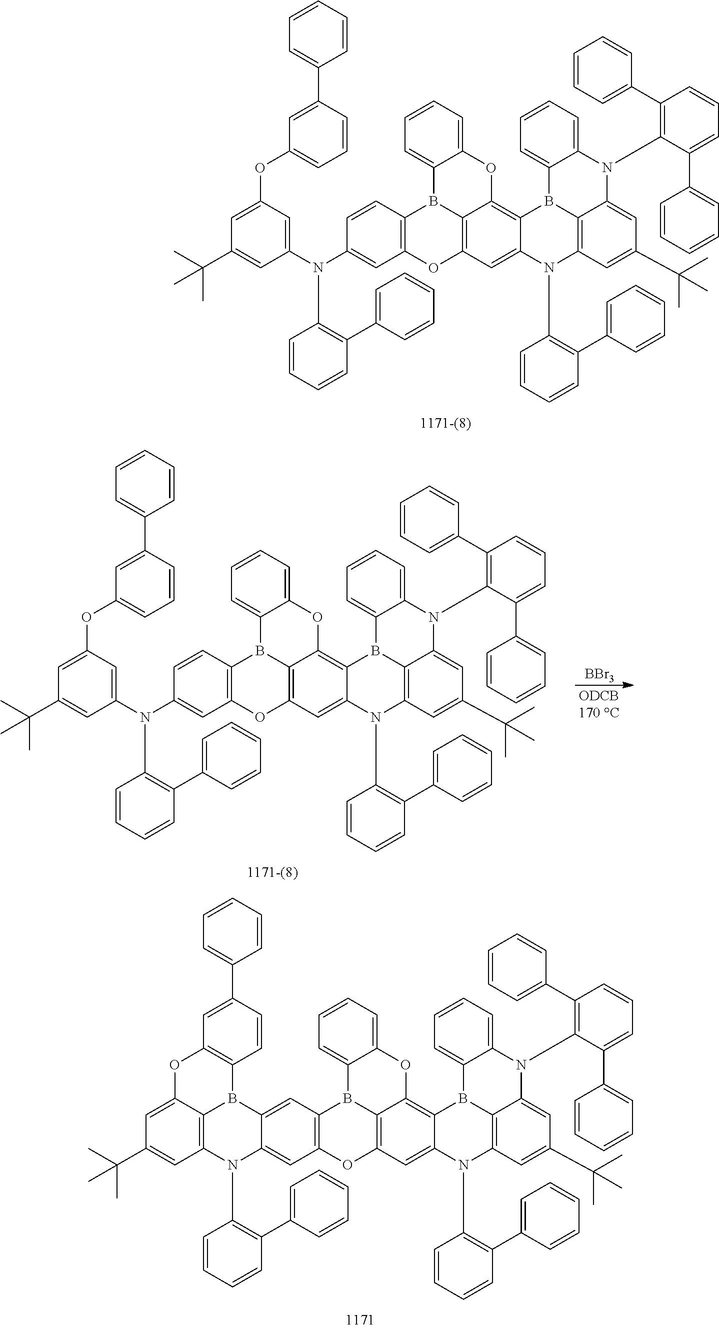

### Synthesis of Intermediate 1171 (1)

In an Ar atmosphere, NMP (602 ml) was added to 1,3-difluoro-5-iodobenzene (60.21 g, 250.89 mmol), phenol (23.61 g, 250.89 mmol), and K₂CO₃ (156.04 g, 1128.98 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1171-(1) (69.35 g, yield: 88%). As measured by FAB MS, Intermediate 1171-(1) had a molecular weight of 314.

### Synthesis of Intermediate 1171-(2)

In an Ar atmosphere, NMP (691 mL) was added to Intermediate 1171-(1) (69.11 g, 220.03 mmol), 3-chlorophenol (28.29 g, 220.03 mmol), and K₂CO₃ (136.84 g, 990.11 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1171-(2) (79.04 g, yield: 85%). As measured by FAB MS, Intermediate 1171-(2) had a molecular weight of 423.

### Synthesis of Intermediate 1171-(3)

1,3-dibromo-5-(tert-butyl)benzene (25.13 g, 86.06 mmol), [1,1′-biphenyl]-3-ol (14.65 g, 86.06 mmol), CuI (18.03 g, 94.66 mmol), K₂CO₃ (47.57 g, 344.23 mmol), and dipivaloylmethane (180.29 g, 0.98 mmol) were added to DMF (1802 mL), and the mixture was heated at a constant outside temperature of 100 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1171-(3) (23.3 g, yield: 71%). As measured by FAB MS, Intermediate 1171-(3) had a molecular weight of 381.

### Synthesis of Intermediate 1171-(4)

In an Ar atmosphere, Intermediate 1171-(3) (22.12 g, 58.01 mmol), [1,1′-biphenyl]-2-amine (11.78 g, 69.61 mmol), Pd(dba)₂ (3.34 g, 5.8 mmol), P(tBu)₃·HBF4 (3.37 g, 11.6 mmol), and tBuONa (12.82 g, 133.42 mmol) were added to toluene (290 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1171-(4) (17.44 g, yield: 64%). As measured by FAB MS, Intermediate 1171-(4) had a molecular weight of 470.

### Synthesis of Intermediate 1171-(5)

In an Ar atmosphere, Intermediate 398-(4) (10.05 g, 18.87 mmol), [1,1′-biphenyl]-2-amine (3.83 g, 22.65 mmol), Pd(dba)₂ (1.09 g, 1.89 mmol), P(tBu)₃·HBF4 (1.1 g, 3.77 mmol), and tBuONa (4.17 g, 43.41 mmol) were added to toluene (94 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1171-(5) (7.85 g, yield: 67%). As measured by FAB MS, Intermediate 1171-(5) had a molecular weight of 621.

### Synthesis of Intermediate 1171-(6)

Intermediate 1171-(5) (7.55 g, 12.16 mmol), Intermediate 1171-(2) (41.12 g, 97.29 mmol), CuI (5.79 g, 30.4 mmol), and K₂CO₃ (25.21 g, 182.41 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1171-(6) (8.24 g, yield: 74%). As measured by FAB MS, Intermediate 1171-(6) had a molecular weight of 916.

### Synthesis of Intermediate 1171-(7)

In an Ar atmosphere, Intermediate 1171-(6) (8.09 g, 8.84 mmol) was dissolved in ODCB (88 mL), BBr₃ (8.85 g, 35.34 mmol) was added, and the mixture was heated and stirred at 170 °C for 10 hours. The reaction solution was cooled to room temperature, DIPEA (13.68 g, 106.03 mmol) was added, and water was added, and then the mixture was subjected to celite filtering and liquid separation to concentrate an organic layer. The concentrated organic layer was purified through silica gel column chromatography to obtain Intermediate 1171-(7) (1.56 g, yield: 19%). As measured by FAB MS, Intermediate 1171-(7) had a molecular weight of 931.

### Synthesis of Intermediate 1171-(8)

In an Ar atmosphere, Intermediate 1171-(7) (1.48 g, 1.59 mmol), Intermediate 1171-(4) (0.9 g, 1.91 mmol), Pd(dba)₂ (0.09 g, 0.16 mmol), P(tBu)₃·HBF4 (0.09 g, 0.32 mmol), and tBuONa (0.35 g, 3.66 mmol) were added to toluene (7 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1171-(8) (1.84 g, yield: 85%). As measured by FAB MS, Intermediate 1171-(8) had a molecular weight of 1364.

### Synthesis of Compound 1171

In an Ar atmosphere, Intermediate 1171-(8) (1.74 g, 1.28 mmol) was dissolved in ODCB (13 mL), BBr₃ (1.28 g, 5.1 mmol) was added, and the mixture was heated and stirred at 170 °C for 10 hours. The reaction solution was cooled to room temperature, DIPEA (1.97 g, 15.3 mmol) was added, and water was added, and then the mixture was subjected to celite filtering and liquid separation to concentrate an organic layer. The concentrated organic layer was purified through silica gel column chromatography to obtain Compound 1171 (0.77 g, yield: 44%). The FAB MS measurement shows that Compound 1171 had a molecular weight of 1372. The obtained Compound 1171 was subjected to sublimation purification (380 °C, 2.3×10⁻³ Pa) and used to prepare a light emitting element.

### (8) Synthesis of Fused Polycyclic Compound 1280

Fused polycyclic Compound 1280 according to one or more embodiments may be synthesized through, for example, a process of Reaction Scheme 8.

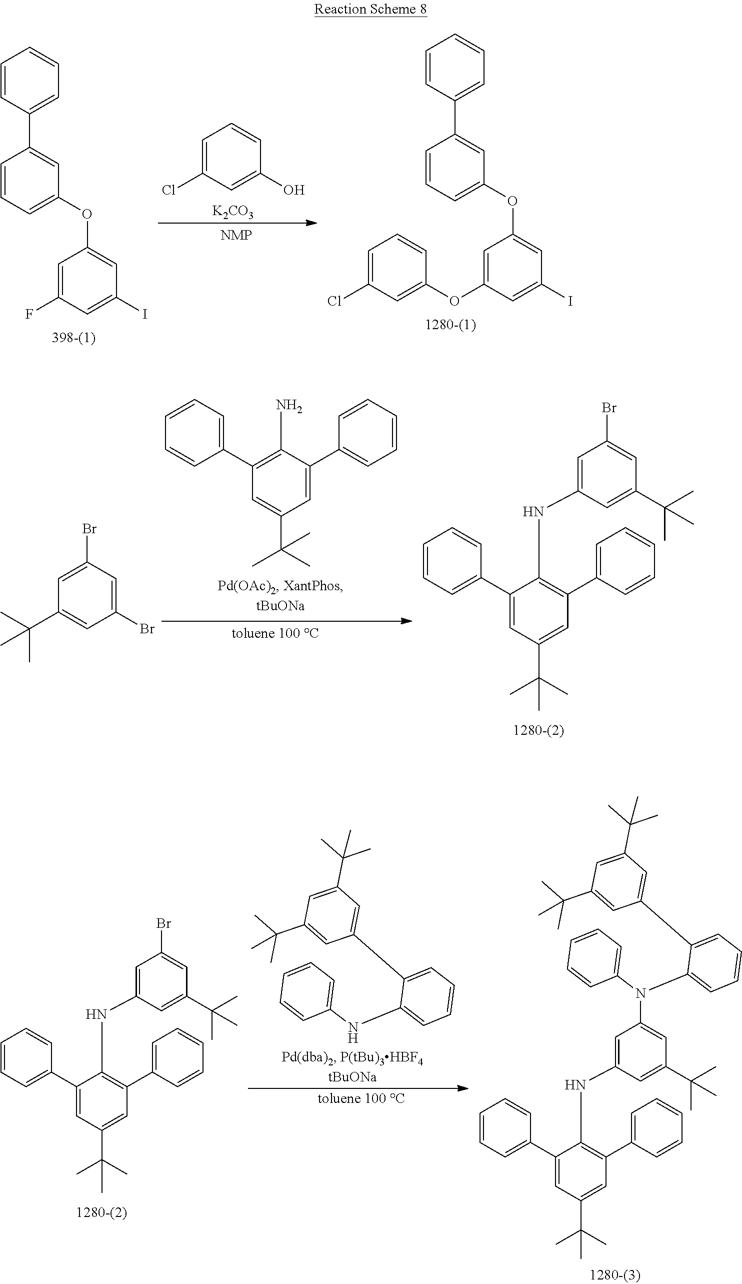

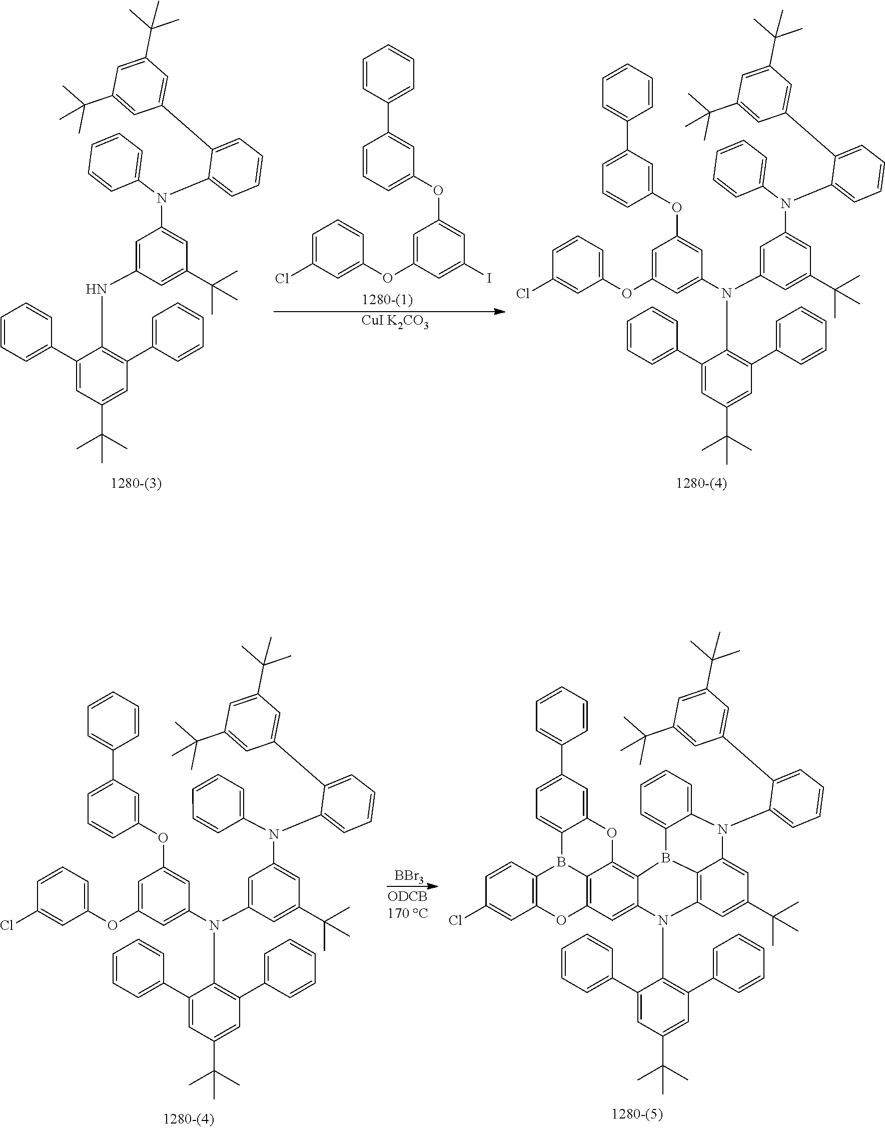

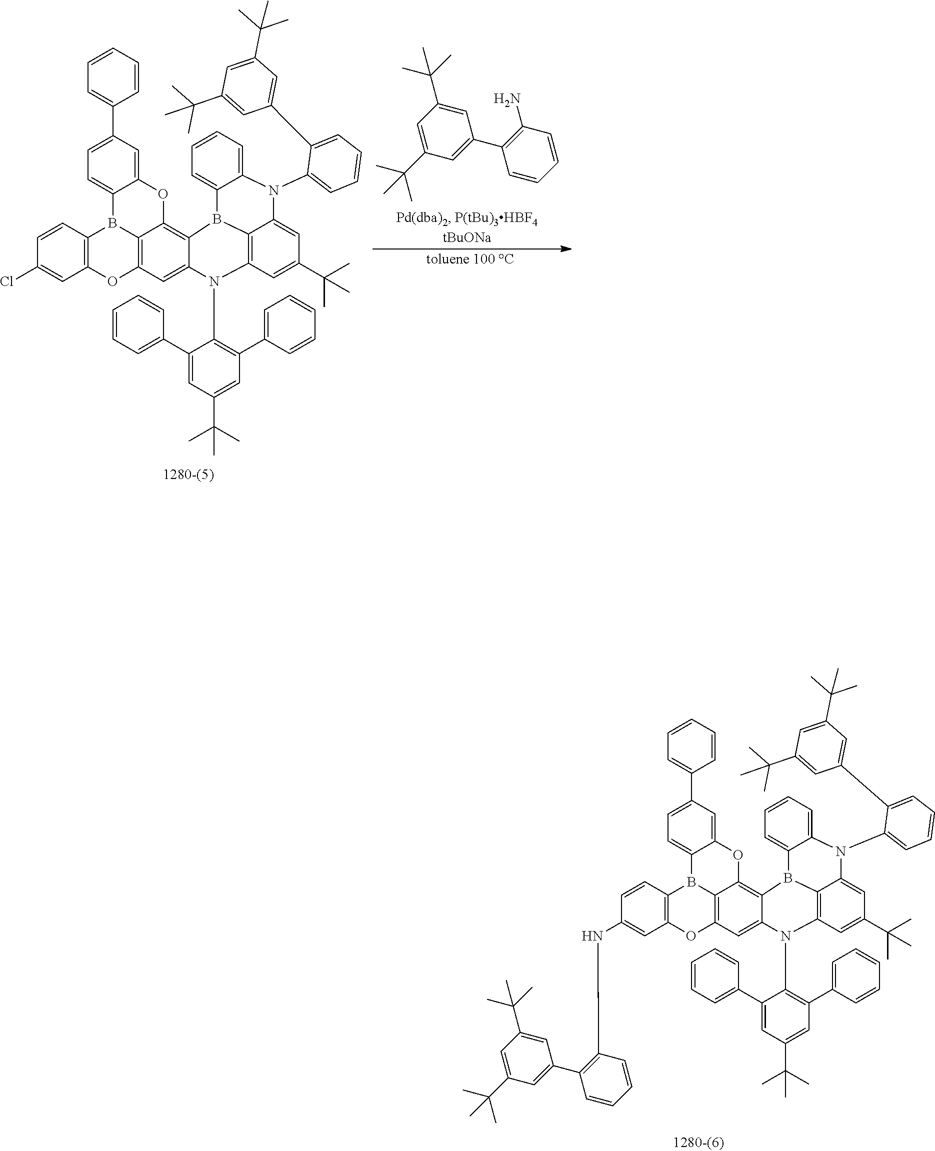

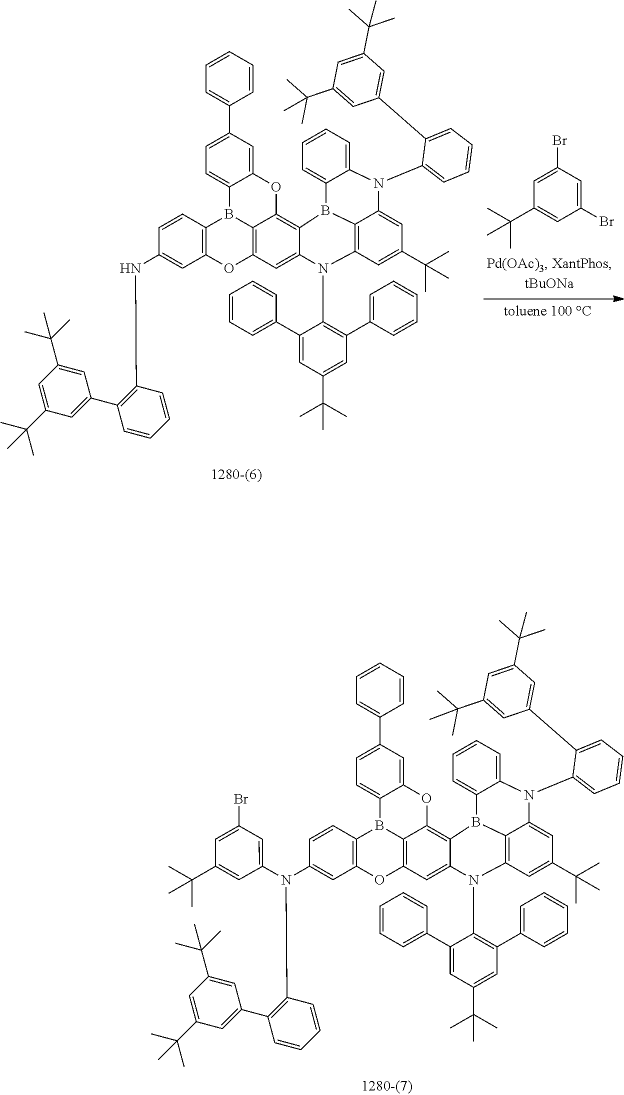 [SMILES: CC(C)(C)c1cc(-c2ccccc2Nc2ccc3c(c2)Oc2cc4c(c5c2B3c2ccc(-c3ccccc3)cc2O5)B2c3ccccc3N(c3ccccc3-c3cc(C(C)(C)C)cc(C(C)(C)C)c3)c3cc(C(C)(C)C)cc(c32)N4c2c(-c3ccccc3)cc(C(C)(C)C)cc2-c2ccccc2)cc(C(C)(C)C)c1 ; CC(C)(C)c1cc(Br)cc(Br)c1 ; CC(C)(C)c1cc(Br)cc(N(c2ccc3c(c2)Oc2cc4c(c5c2B3c2ccc(-c3ccccc3)cc2O5)B2c3ccccc3N(c3ccccc3-c3cc(C(C)(C)C)cc(C(C)(C)C)c3)c3cc(C(C)(C)C)cc(c32)N4c2c(-c3ccccc3)cc(C(C)(C)C)cc2-c2ccccc2)c2ccccc2-c2cc(C(C)(C)C)cc(C(C)(C)C)c2)c1]

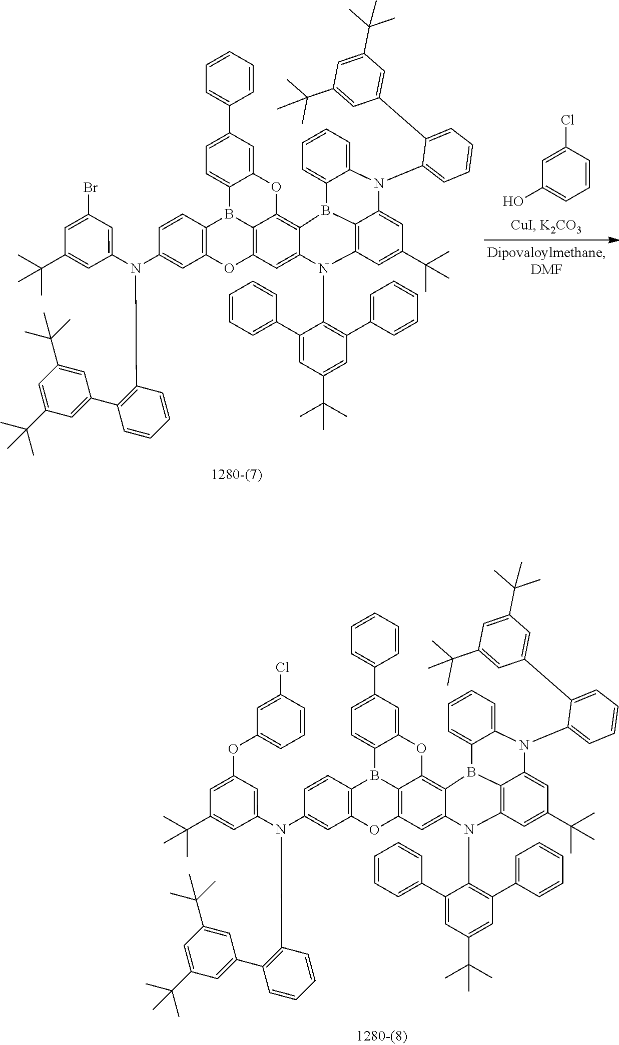 [SMILES: CC(C)(C)c1cc(Br)cc(N(c2ccc3c(c2)Oc2cc4c(c5c2B3c2ccc(-c3ccccc3)cc2O5)B2c3ccccc3N(c3ccccc3-c3cc(C(C)(C)C)cc(C(C)(C)C)c3)c3cc(C(C)(C)C)cc(c32)N4c2c(-c3ccccc3)cc(C(C)(C)C)cc2-c2ccccc2)c2ccccc2-c2cc(C(C)(C)C)cc(C(C)(C)C)c2)c1 ; Oc1cccc(Cl)c1 ; CC(C)(C)c1cc(Oc2cccc(Cl)c2)cc(N(c2ccc3c(c2)Oc2cc4c(c5c2B3c2ccc(-c3ccccc3)cc2O5)B2c3ccccc3N(c3ccccc3-c3cc(C(C)(C)C)cc(C(C)(C)C)c3)c3cc(C(C)(C)C)cc(c32)N4c2c(-c3ccccc3)cc(C(C)(C)C)cc2-c2ccccc2)c2ccccc2-c2cc(C(C)(C)C)cc(C(C)(C)C)c2)c1]

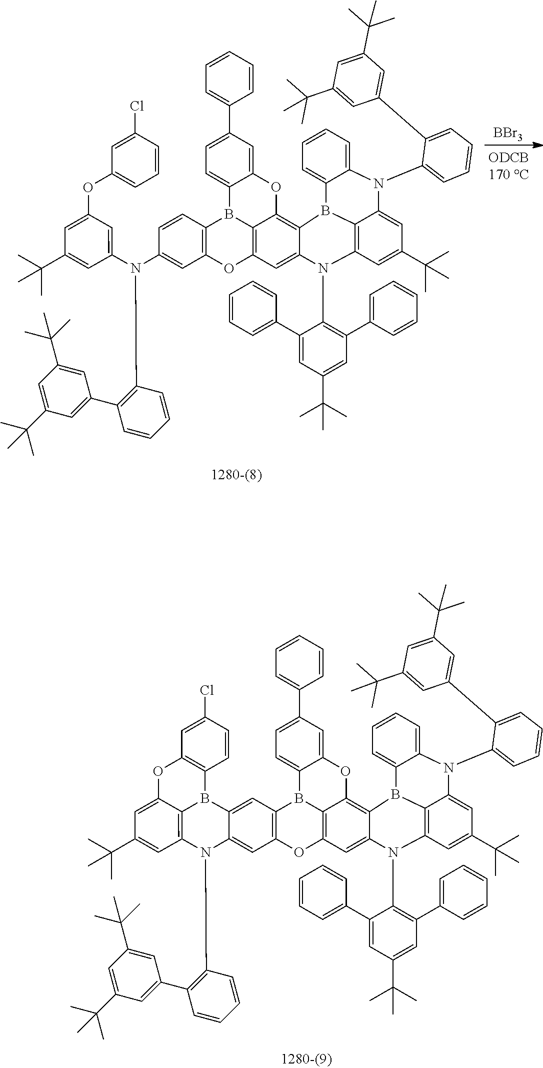

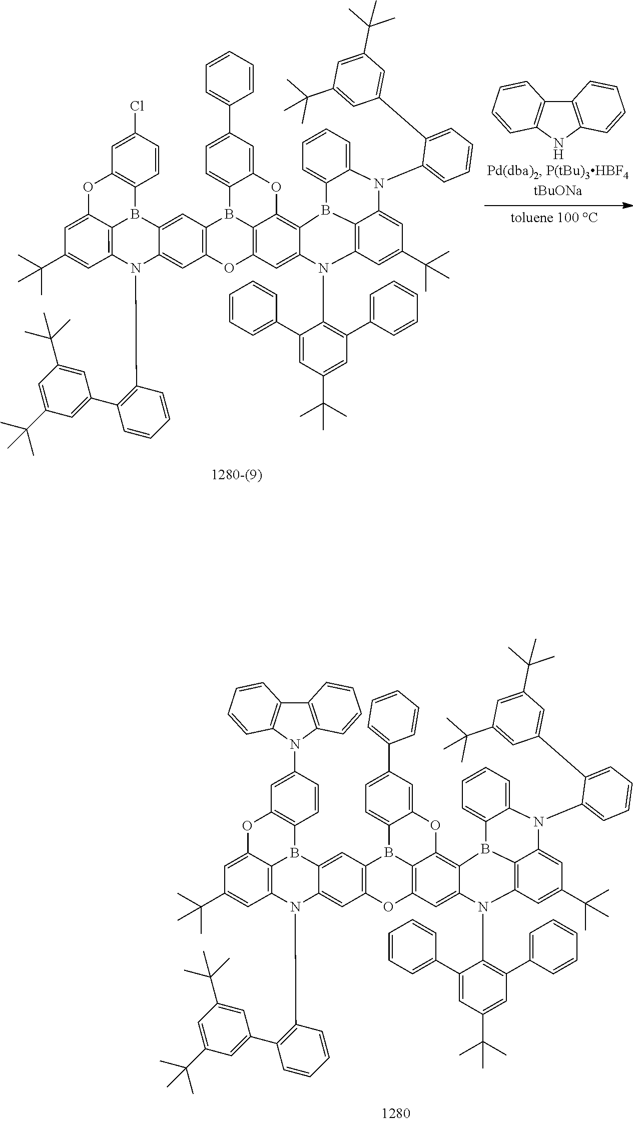

### Synthesis of Intermediate 1280-(1)

In an Ar atmosphere, NMP (486 ml) was added to Intermediate 398-(1) (48.66 g, 124.71 mmol), 3-chlorophenol (16.03 g, 124.71 mmol), and K₂CO₃ (77.56 g, 561.17 mmol), and the mixture was heated at a constant outside temperature of 140 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1280-(1) (54.73 g, yield: 88%). As measured by FAB MS, Intermediate 1280-(1) had a molecular weight of 499.

### Synthesis of Intermediate 1280-(2)

In an Ar atmosphere, 1,3-dibromo-5-(tert-butyl)benzene (20.01 g, 68.53 mmol), 5′-(tert-butyl)-[1,1′:3′,1″-terphenyl]-2′-amine (20.66 g, 68.53 mmol), Pd(OAc)₂ (0.46 g, 2.06 mmol), XantPhos (2.38 g, 4.11 mmol), and tBuONa (7.9 g, 82.23 mmol) were added to toluene (342 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1280-(2) (28.45 g, yield: 81%). As measured by FAB MS, Intermediate 1280-(2) had a molecular weight of 513.

### Synthesis of Intermediate 1280-(3)

In an Ar atmosphere, Intermediate 1280-(2) (28.11 g, 54.84 mmol), 3′,5′-di-tert-butyl-N-phenyl-[1,1′-biphenyl]-2-amine (23.53 g, 65.81 mmol), Pd(dba)₂ (3.15 g, 5.48 mmol), P(tBu)₃·HBF4 (3.18 g, 10.97 mmol), and tBuONa (12.12 g, 126.14 mmol) were added to toluene (274 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1280-(3) (35.49 g, yield: 82%). As measured by FAB MS, Intermediate 1280-(3) had a molecular weight of 789.

### Synthesis of Intermediate 1280-(4)

Intermediate 1280-(3) (10.25 g, 12.99 mmol), Intermediate 1280-(1) (51.82 g, 103.91 mmol), CuI (6.18 g, 32.47 mmol), and K₂CO₃ (26.93 g, 194.83 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1280-(4) (10.7 g, yield: 71%). As measured by FAB MS, Intermediate 1280-(4) had a molecular weight of 1160.

### Synthesis of Intermediate 1280-(5)

In an Ar atmosphere, Intermediate 1280-(4) (10.52 g, 9.07 mmol) was dissolved in ODCB (91 mL), BBr₃ (9.09 g, 36.28 mmol) was added, and the mixture was heated and stirred at 170 °C for 10 hours. The reaction solution was cooled to room temperature, DIPEA (14.04 g, 108.83 mmol) was added, and water was added, and then the mixture was subjected to celite filtering and liquid separation to concentrate an organic layer. The concentrated organic layer was purified through silica gel column chromatography to obtain Intermediate 1280-(5) (1.71 g, yield: 16%). As measured by FAB MS, Intermediate 1280-(5) had a molecular weight of 1176.

### Synthesis of Intermediate 1280-(6)

In an Ar atmosphere, Intermediate 1280-(5) (1.65 g, 1.4 mmol), 3′,5′-di-tert-butyl-[1,1′-biphenyl]-2-amine (0.47 g, 1.68 mmol), Pd(dba)₂ (0.08 g, 0.14 mmol), P(tBu)₃·HBF4 (0.08 g, 0.28 mmol), and tBuONa (0.31 g, 3.23 mmol) were added to toluene (7 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1280-(6) (1.34 g, yield: 67%). As measured by FAB MS, Intermediate 1280-(6) had a molecular weight of 1421.

### Synthesis of Intermediate 1280-(7)

In an Ar atmosphere, Intermediate 1280-(6) (1.22 g, 0.86 mmol), 1,3-dibromo-5-(tert-butyl)benzene (0.25 g, 0.86 mmol), Pd(OAc)₂ (0.01 g, 0.03 mmol), XantPhos (0.03 g, 0.05 mmol), and tBuONa (0.1 g, 1.03 mmol) were added to toluene (4 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Intermediate 1280-(7) (1.19 g, yield: 85%). As measured by FAB MS, Intermediate 1280-(7) had a molecular weight of 1632.

### Synthesis of Intermediate 1280-(8)

Intermediate 1280-(7) (1.11 g, 0.68 mmol), 3-chlorophenol (0.7 g, 5.44 mmol), CuI (0.32 g, 1.7 mmol), and K₂CO₃ (1.41 g, 10.2 mmol) were added to a small amount of toluene (about 10 mL), and the mixture was heated at a constant outside temperature of 215 °C for 24 hours. After cooling, water was added after the reaction solution was diluted with CH₂Cl₂, and the mixture was subjected to celite filtering and liquid separation to concentrate an organic layer. The concentrated organic layer was purified through silica gel column chromatography to obtain Intermediate 1280-(8) (0.79 g, yield: 69%). As measured by FAB MS, Intermediate 1280-(8) had a molecular weight of 1679.

### Synthesis of Intermediate 1280-(9)

In an Ar atmosphere, Intermediate 1280-(8) (0.75 g, 0.45 mmol) was dissolved in ODCB (4 mL), BBr₃ (0.45 g, 1.79 mmol) was added, and the mixture was heated and stirred at 170 °C for 10 hours. The reaction solution was cooled to room temperature, DIPEA (0.69 g, 5.36 mmol) was added, and water was added, and then the mixture was subjected to celite filtering and liquid separation to concentrate an organic layer. The concentrated organic layer was purified through silica gel column chromatography to obtain Intermediate 1280-(9) (0.36 g, yield: 48%). As measured by FAB MS, Intermediate 1280-(9) had a molecular weight of 1687.

### Synthesis of Compound 1280

In an Ar atmosphere, Intermediate 1280-(9) (0.34 g, 0.2 mmol), 9H-carbazole (0.04 g, 0.24 mmol), Pd(dba)₂ (0.01 g, 0.02 mmol), P(tBu)₃·HBF4 (0.01 g, 0.04 mmol), and tBuONa (0.04 g, 0.46 mmol) were added to toluene (1 mL), and the mixture was heated and stirred at 100 °C for 8 hours. After cooling, water was added to the reaction solution, and the mixture was subjected to celite filtering and liquid separation to concentrate an organic layer. The concentrated organic layer was purified through silica gel column chromatography to obtain Compound 1280 (0.32 g, yield: 86%). The FAB MS measurement shows that Compound 1280 had a molecular weight of 1818. The obtained Compound 1280 was subjected to sublimation purification (390 °C, 2.8×10⁻³ Pa) and used to prepare a light emitting element.

### 2. Preparation and Evaluation of Light Emitting Element

### (1) Preparation of Light Emitting Element

Light emitting elements including fused polycyclic compounds according to an embodiment or Comparative Example Compounds were each prepared through a method below. Light emitting elements of Examples 1 to 8 were respectively prepared using Compounds 398, 503, 839, 1043, 1074, 1117, 1171, and 1280, each of which is a fused polycyclic compound according to an embodiment, as a dopant material of emission layer. Light emitting elements of Comparative Examples 1 to 9 were respectively prepared using Comparative Example Compounds X1 to X9 as a dopant material of emission layer.

As a first electrode, an ITO having a thickness of 150 nm was patterned on a glass substrate, washed with ultrapure water, and UV ozone-treated for 10 minutes. Thereafter, a hole injection layer having a thickness of 10 nm was formed using HAT-CN, and a hole transport layer having a thickness of 80 nm was formed using α-NPD on the hole injection layer.

Then, an electron blocking layer having a thickness of 5 nm was formed using mCP, and respective Example Compound or Comparative Example Compounds and mCBP were provided at a weight ratio of 1:99 to form an emission layer. The emission layer was formed to have a thickness of 20 nm. On the emission layer, an electron transport layer having a thickness of 30 nm was formed using TPBi, and an electron injection layer having a thickness of 0.5 nm was formed using LiF on the electron transport layer. Then, a second electrode having a thickness of 100 nm was formed using aluminum (Al) on the electron injection layer. The hole injection layer, the hole transport layer, the electron blocking layer, the emission layer, the electron transport layer, the electron injection layer, and the second electrode were each formed using a vacuum deposition apparatus.

### Example Compound

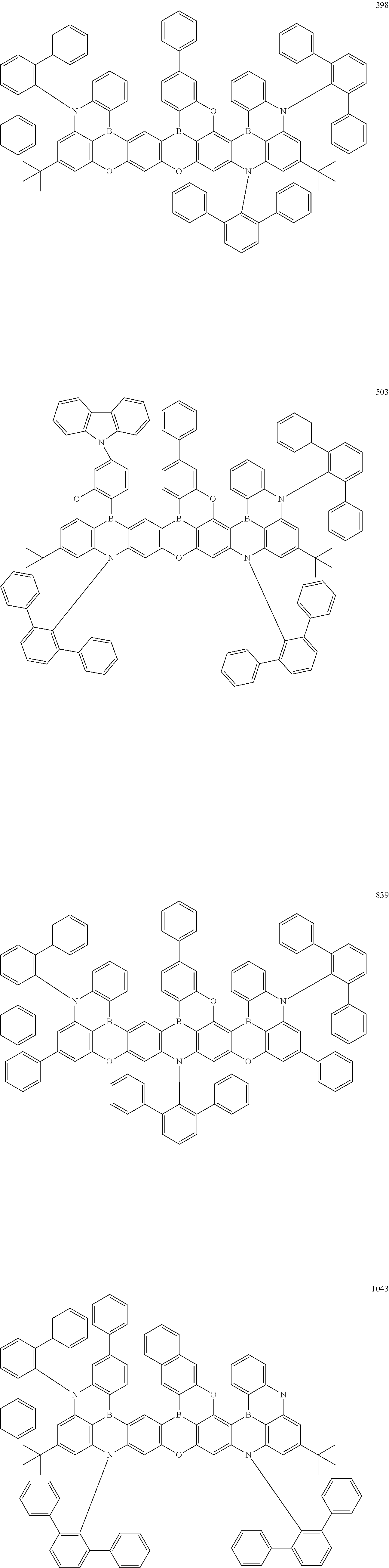

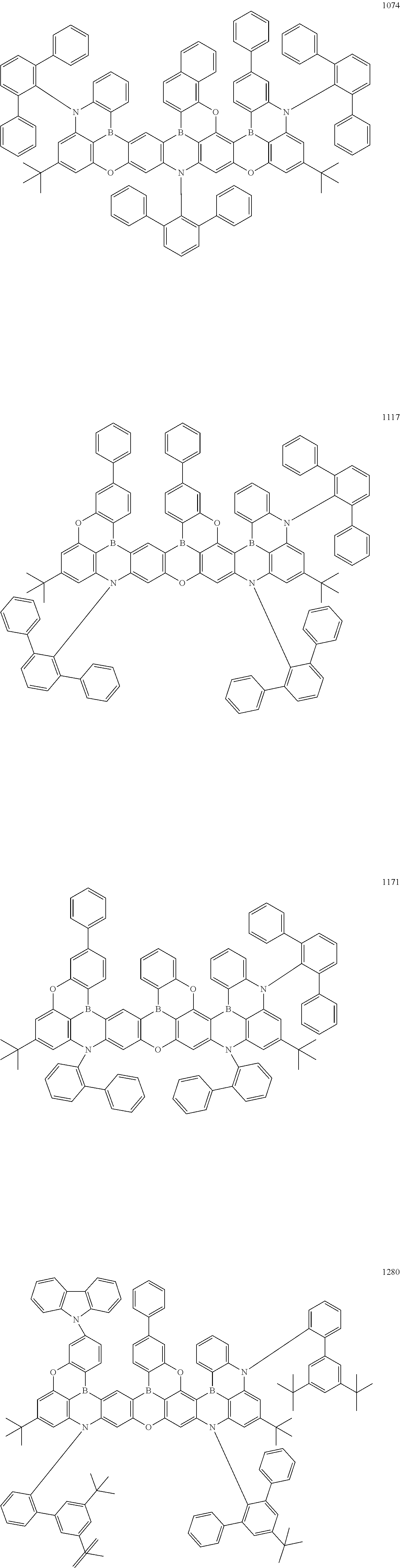

### Comparative Example Compound

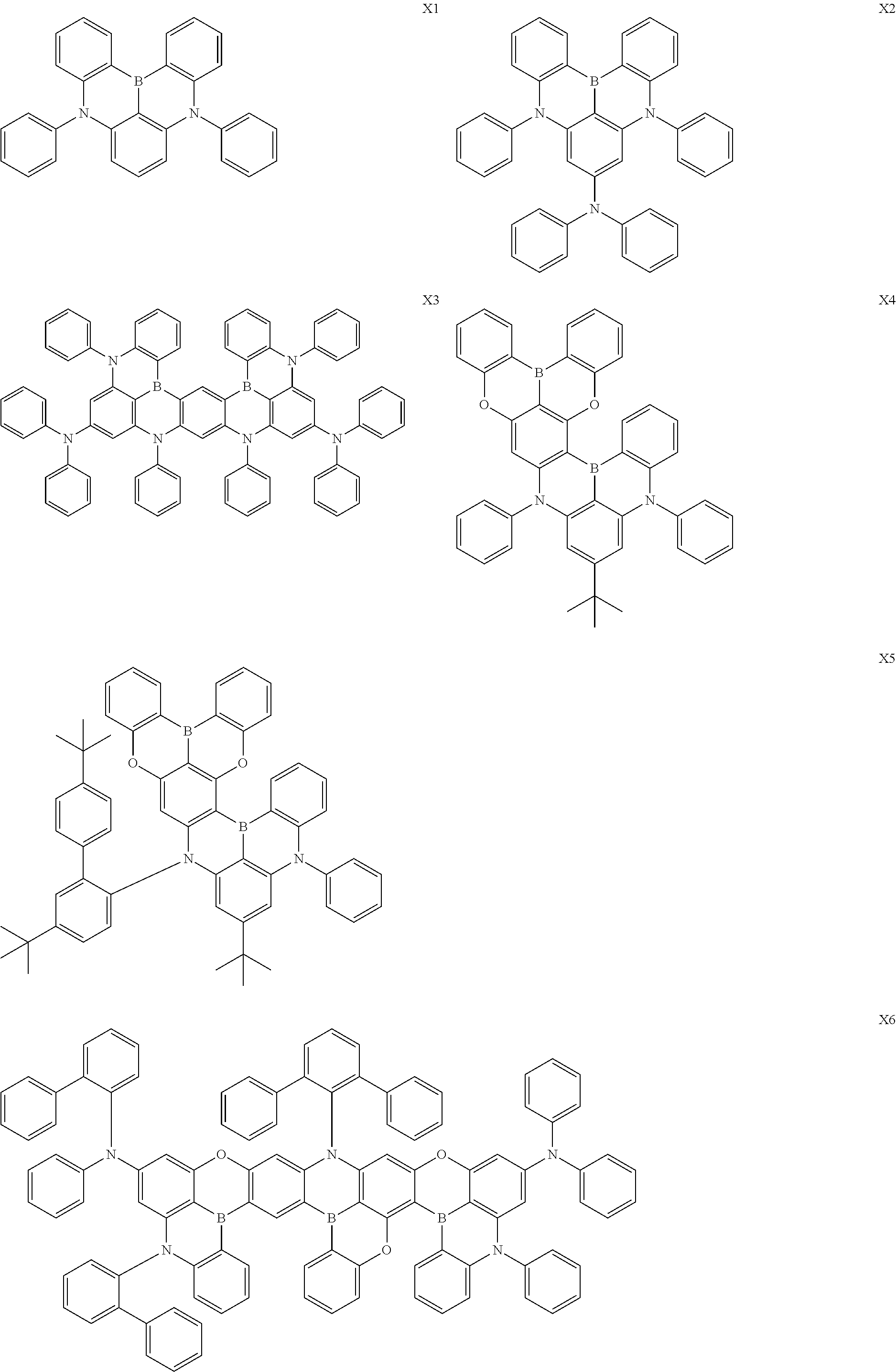

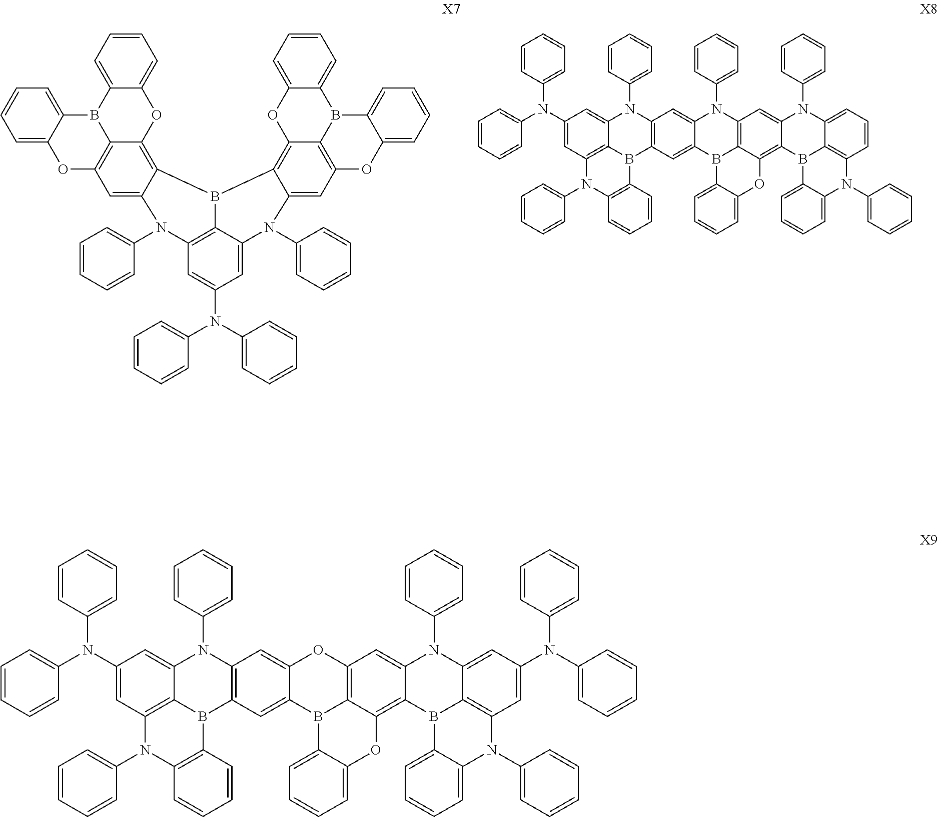 [SMILES: c1ccc(N(c2ccccc2)c2cc3c4c(c2)N(c2ccccc2)c2cc5c6c(c2B4c2c(cc4c7c2Oc2ccccc2B7c2ccccc2O4)N3c2ccccc2)Oc2ccccc2B6c2ccccc2O5)cc1 ; c1ccc(N(c2ccccc2)c2cc3c4c(c2)N(c2ccccc2)c2cc5c(cc2B4c2ccccc2N3c2ccccc2)B2c3ccccc3Oc3c2c(cc2c3B3c4ccccc4N(c4ccccc4)c4cccc(c43)N2c2ccccc2)N5c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3Oc3c2c(cc2c3B3c4ccccc4N(c4ccccc4)c4cc(N(c6ccccc6)c6ccccc6)cc(c43)N2c2ccccc2)O5)cc1]

### (2) Evaluation of Light Emitting Element

Table 2 shows evaluation results of each of the light emitting elements of Examples and Comparative Examples. The light emitting elements of Examples and Comparative Examples were each evaluated on maximum emission wavelength (λₘₐₓ) and lifespan (LT₅₀). The maximum emission wavelength (λₘₐₓ) and the lifespan (LT₅₀) were measured using an external quantum efficiency measurement device C9920-12 from Hamamatsu Photonics. The lifespan (LT₅₀) is indicated by measuring luminance half-life with respect to an initial luminance of 100 cd/m², and is indicated as a relative value with respect to the lifespan of Comparative Example 3. The maximum emission wavelength (λₘₐₓ) indicates a wavelength at which a maximum emission intensity value is observed in an emission spectrum.

TABLE 2

| Example of element | | | |
|---|---|---|---|
| preparation | Dopant | λₘₐₓ (nm) | LT₅₀ |
| Example 1 | Compound 398 | 458 | 3.1 |
| Example 2 | Compound 503 | 462 | 4.0 |
| Example 3 | Compound 839 | 463 | 4.6 |
| Example 4 | Compound 1043 | 463 | 4.3 |
| Example 5 | Compound 1074 | 462 | 4.4 |
| Example 6 | Compound 1117 | 459 | 3.9 |
| Example 7 | Compound 1171 | 458 | 3.2 |
| Example 8 | Compound 1280 | 461 | 4.2 |
| Comparative | Comparative Example | 457 | 0.3 |
| Example 1 | Compound X1 | | |
| Comparative | Comparative Example | 446 | 0.2 |
| Example 2 | Compound X2 | | |
| Comparative | Comparative Example | 467 | 1.0 |
| Example 3 | Compound X3 | | |
| Comparative | Comparative Example | 455 | 0.8 |
| Example 4 | Compound X4 | | |
| Comparative | Comparative Example | 457 | 1.2 |
| Example 5 | Compound X5 | | |
| Comparative | Comparative Example | 468 | 1.5 |
| Example 6 | Compound X6 | | |
| Comparative | Comparative Example | 450 | 0.8 |
| Example 7 | Compound X7 | | |
| Comparative | Comparative Example | 480 | 0.8 |
| Example 8 | Compound X8 | | |
| Comparative | Comparative Example | 475 | 0.7 |
| Example 9 | Compound X9 | | |

Referring to Table 2, it is seen that the light emitting elements of Examples 1 to 8 and Comparative Examples 1 to 7 each exhibit a maximum emission wavelength in a wavelength range of 450 nm to 470 nm. It is seen that, compared to the light emitting element of Comparative Example 1 to 9, the light emitting elements of Examples 1 to 8 each exhibit long lifespan. It is seen that, compared to the light emitting element of Comparative Example 3, the light emitting elements of Examples 1 to 8 exhibit an improvement in lifespan of 3.1 times to 4.6 times.

The light emitting elements of Examples 1 to 8 respectively include Compounds 398, 503, 839, 1043, 1074, 1117, 1171, and 1280, and Compounds 398, 503, 839, 1043, 1074, 1117, 1171, and 1280 are each a fused polycyclic compound according to an embodiment. Compounds 398, 503, 839, 1043, 1074, 1117, 1171, and 1280 each include a fused ring of 13 rings as a central structure, and the central structure includes at least one substituent (e.g., a t-butyl group, a phenyl group, and/or a carbazole group) instead of a hydrogen. Accordingly, a light emitting element including the fused polycyclic compound according to one or more embodiments may exhibit long lifespan characteristics.

Calculation of the molecular orbitals of Compounds 398, 503, 839, 1043, 1074, 1117, 1171, and 1280 using Gaussian shows that these compounds are each of the CT (Charge Transfer) type (kind), in which the distribution of the HOMO and LUMO orbitals is separated.

The light emitting elements of Comparative Examples 1 to 3 include Comparative Example Compounds X1 to X3, respectively, and Comparative Example Compounds X1 to X3 are each an MR-type (kind) compound. Comparative Example Compounds X1 and X2 each include a fused ring of five rings as a central structure, and Comparative Example Compound X3 includes a fused ring of nine rings as a central structure, which is different from the fused polycyclic compound according to one or more embodiments of the present disclosure. Accordingly, the light emitting elements of Comparative Examples 1 to 3 exhibit short lifespan.

The light emitting elements of Comparative Examples 4 and 5 include Comparative Example Compounds X4 and X5, respectively, and Comparative Example Compounds X4 and X5 are each a 2B-MRCT-type (kind) compound. Comparative Example Compounds X4 and X5 each include a fused ring of nine rings as a central structure, which is different from the fused polycyclic compound according to one or more embodiments of the present disclosure. Accordingly, the light emitting elements of Comparative Examples 4 and 5 exhibit short lifespan.

The light emitting element of Comparative Example 6 includes Comparative Example Compound X6, and Comparative Example Compound X6 includes a fused ring of 13 rings as a central structure. However, Comparative Example Compound X6 corresponds to a case in which in Formula 1 described above, G² and G¹⁷ are CR^{x1} and CR^{x2}, respectively, and R^{x1} and R^{x2} are each a substituted or unsubstituted amine group, which is different from the fused polycyclic compound according to one or more embodiments of the present disclosure. Accordingly, the light emitting element of Comparative Example 6 exhibits short lifespan.

The light emitting element of Comparative Example 7 includes Comparative Example Compound X7, and Comparative Example Compound X7 includes a fused ring of 13 rings as a central structure. However, the central structure included in Comparative Example Compound X7 is different from that of the fuse polycyclic compound according to one or more embodiments of the present disclosure. Accordingly, the light emitting element of Comparative Example 7 exhibits short lifespan.

In Comparative Example Compound X7 shown below, MO-71 to MO-73 are indicated for convenience of description. ‘MO-71’ is a moiety in which HOMO orbital is distributed, and ‘MO-72’ and ‘MO-73’ are moieties in which LUMO orbital is distributed.

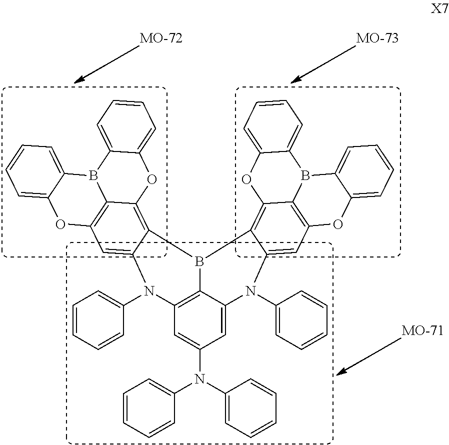

Comparative Example Compound X7 shows that the HOMO orbital distribution is concentrated on a lower boron atom, and the LUMO orbital distribution is concentrated on two upper boron atoms. The LUMO orbital distributions at the two boron atoms are found to be independent of each other. As such, Comparative Example Compound X7, in which the LUMO orbital distributions are not unified but separated, fails to exhibit improved luminous characteristics due to insufficient conjugation of the LUMO orbitals.

It is seen that the light emitting element of Comparative Example 8 exhibits a maximum emission wavelength in a long wavelength range exceeding 470 nm. The light emitting element of Comparative Example 8 includes Comparative Example Compound X8, and Comparative Example Compound X8 includes a fused ring of 13 rings as a central structure. However, Comparative Example Compound X8 corresponds to a case in which in Formula 1 described above G² is CR^{x1} (or CR^{x2}), and R^{x1} (or R^{x2}) is a substituted or unsubstituted amine group, which is different from the fused polycyclic compound according to one or more embodiments of the present disclosure. Accordingly, the light emitting element of Comparative Example 8 exhibits short lifespan.

It is seen that the light emitting element of Comparative Example 9 exhibits a maximum emission wavelength in a long wavelength range exceeding 470 nm. The light emitting element of Comparative Example 9 includes Comparative Example Compound X9, and Comparative Example Compound X9 includes a fused ring of 13 rings as a central structure. However, Comparative Example Compound X9 corresponds to a case in which in Formula 1 described above G² and G¹⁷ are CR^{x1} and CR^{x2}, respectively, and R^{x1} and R^{x2} are each a substituted or unsubstituted amine group, which is different from the fused polycyclic compound according to one or more embodiments of the present disclosure. Accordingly, the light emitting element of Comparative Example 9 exhibits short lifespan.

In one or more embodiments, an electronic apparatus may include a light emitting element. In one or more embodiments, the light emitting element may include a fused polycyclic compound in an emission layer thereof. The fused polycyclic compound according to one or more embodiments may include a fused ring of 13 rings as a central structure, and the central structure may have at least one substituent bonded thereto instead of a hydrogen. Accordingly, the fused polycyclic compound according to one or more embodiments may exhibit strong emission intensity and high absorbance, and may contribute to improving lifespan of the light emitting element. The light emitting element including the fused polycyclic compound according to one or more embodiments may exhibit long lifespan characteristics. In one or more embodiments, an electronic apparatus including the light emitting element may exhibit excellent or suitable display quality and excellent or suitable reliability.

A light emitting element according to one or more embodiments and an electronic apparatus including the light emitting element include a fused polycyclic compound according to one or more embodiments, and may thus exhibit long lifespan.

A fused polycyclic compound according to one or more embodiments may contribute to long lifespan of a light emitting element.

In the present disclosure, expressions such as “at least one of,” “one of,” and “selected from,” when preceding a list of elements, modify the entire list of elements and do not modify the individual elements of the list. For example, “at least one of a, b, or c,” “at least one selected from among a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims.

Therefore, the technical scope of the disclosure is not to be limited to the content stated in the detailed description of the disclosure, but should be determined by the claims and equivalents thereof.

What is claimed is:

1. A light emitting element, comprising:
a first electrode;
a second electrode on the first electrode; and
an emission layer between the first electrode and the second electrode, and comprising a first compound represented by Formula 1: 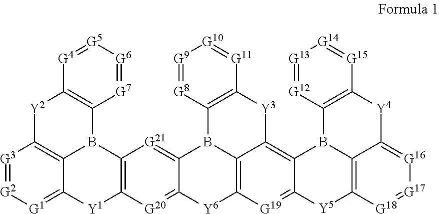
wherein in Formula 1,
Y¹ to Y⁶ are each independently O, S, or NR^{y},
at least one selected from among G¹ to G²¹ is CR^{x1}, and the others are each independently N or CR^{x2}
R^{x1} is deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
R^{x2} and R^{y} are each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
when G² is CR^{x1} or CR^{x2}, then R^{x1} and R^{x2} are not substituted or unsubstituted amine groups,
when G¹⁷ is CR^{x1} or CR^{x2}, then R^{x1} and R^{x2} are not substituted or unsubstituted amine groups, and
the first compound comprises a chemical structure in which one or more hydrogens of the compound are optionally substituted with deuterium.

2. The light emitting element of claim 1, wherein the emission layer further comprises at least one of a second compound represented by Formula HT-1, a third compound represented by Formula ET-1, or a fourth compound represented by Formula D-1: 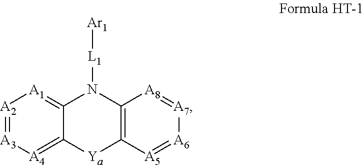
wherein in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring; 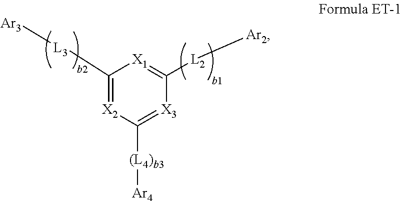
wherein in Formula ET-1,
at least one selected from among X₁ to X₃ is N and the others are CR₅₆,
R₅₆ is hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; and 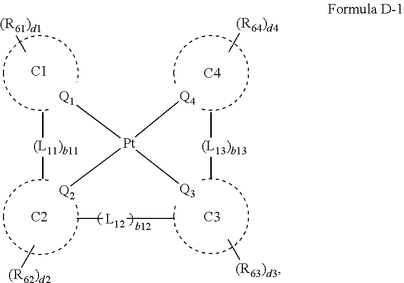
wherein in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
L₁₁ to L₁₃ are each independently a direct linkage, *—O—*, *—S—*, 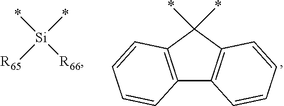
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

3. The light emitting element of claim 1, wherein the first compound represented by Formula 1 is represented by any one selected by Formulas 1-A1 to 1-A8: 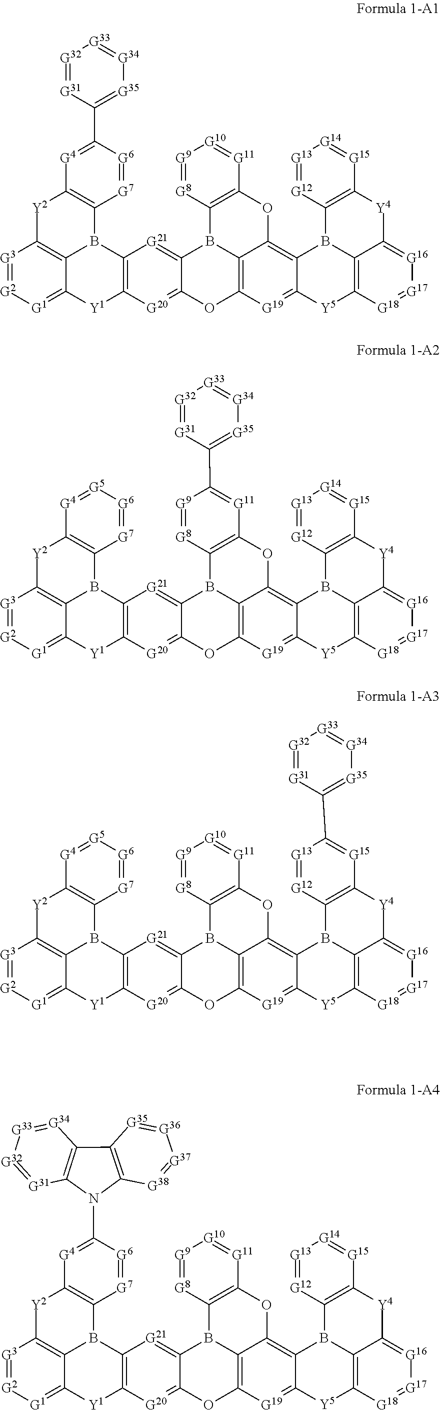 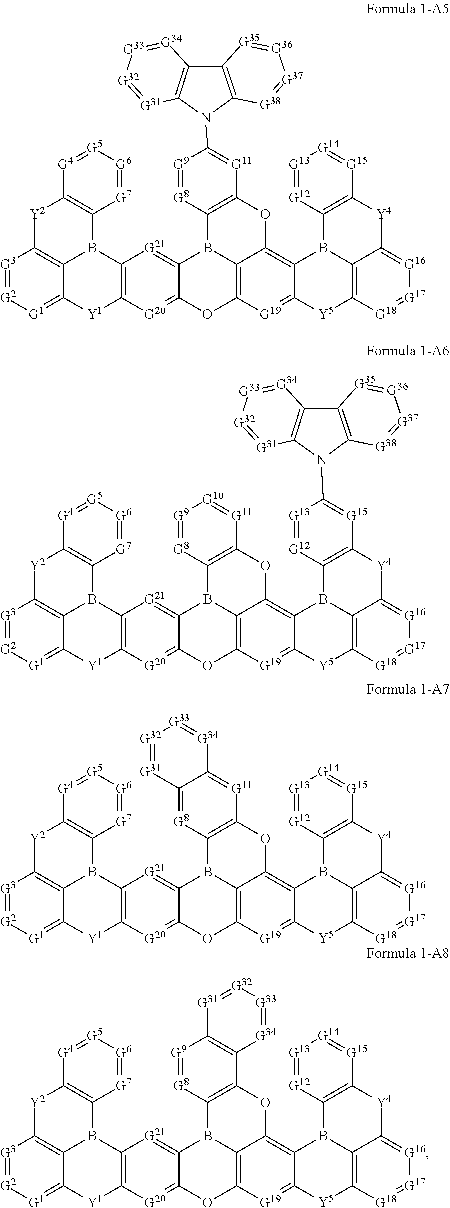
in Formulas 1-A1 to 1-A8,
G³¹ to G³⁸ being each independently N or CR^{X3},
R^{X3} being hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
Y¹, Y², Y⁴, and Y⁵, and G¹ to G²¹ being each the same as defined in Formula 1.

4. The light emitting element of claim 1, wherein the first compound represented by Formula 1 is represented by any one selected from among Formulas 1-B1 to 1-B4: 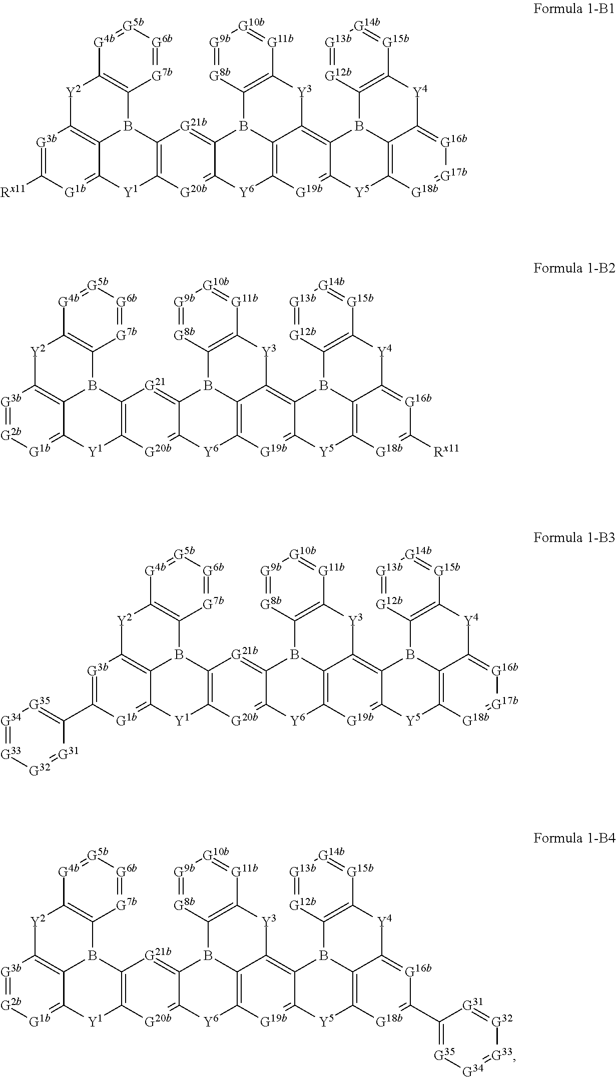
in Formulas 1-B1 to 1-B4,
G^{1b} to G^{21b} and G³¹ to G³⁵ being each independently N or CR^{x2},
R^{x11} being a substituted or unsubstituted alkyl group having 1 to 20 carbon atoms, and
Y¹ to Y⁶ and R^{x2} being each the same as defined in Formula 1.

5. The light emitting element of claim 1, wherein the first compound represented by Formula 1 is represented by Formula 2: 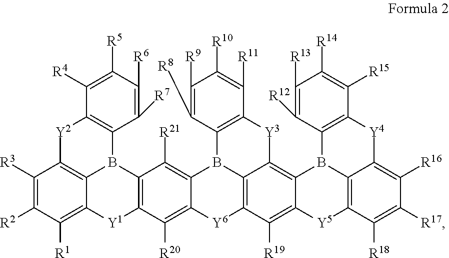
in Formula 2,
R¹ to R²¹ being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-20 forming carbon atoms, or a substituted or unsubstituted heteroaryl group having 3 to 30 ring-forming carbon atoms, and/or bonded to an adjacent group to form a ring,
at least one selected from among R¹ to R²¹ being not hydrogen,
R² and R¹⁷ being not each a substituted or unsubstituted amine group, and
Y¹ to Y⁶ being each the same as defined in Formula 1.

6. The light emitting element of claim 5, wherein the first compound represented by Formula 2 is represented by any one selected from among Formulas 2-A1 to 2-A5 and Formulas 2-B1 to 2-B10: 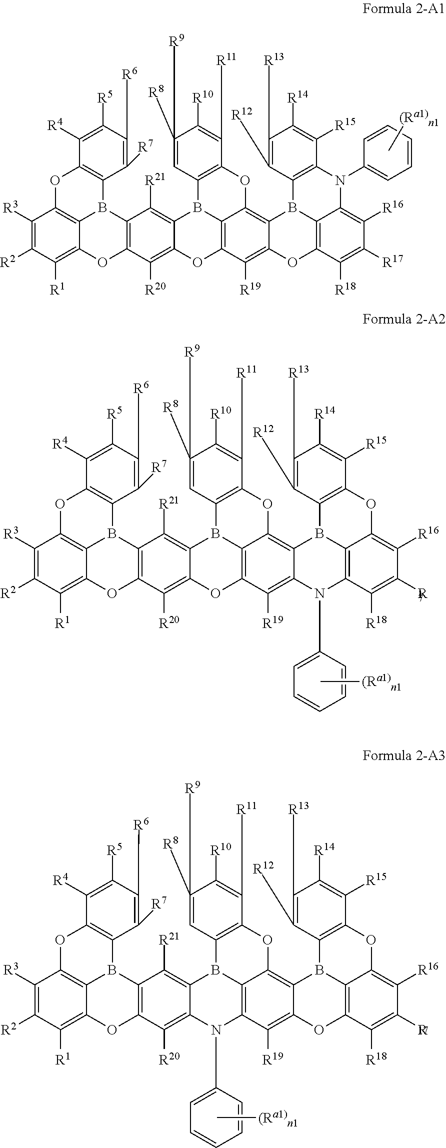 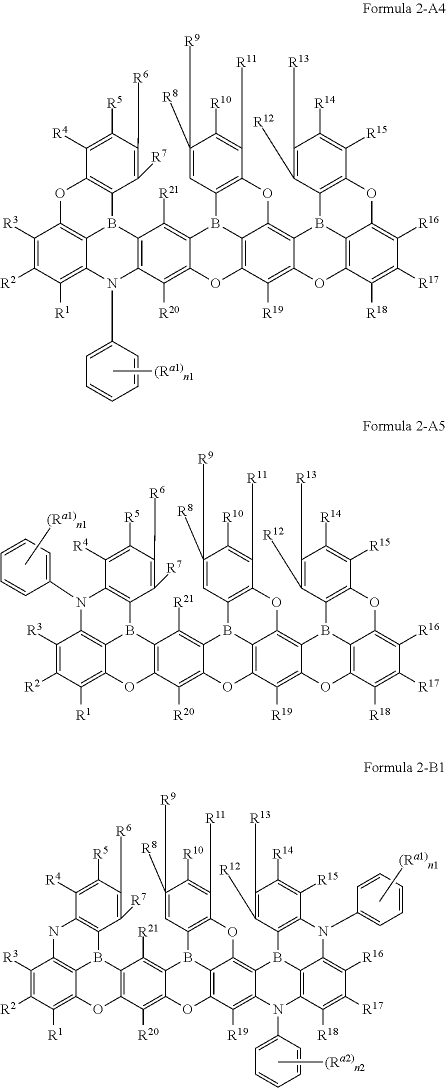 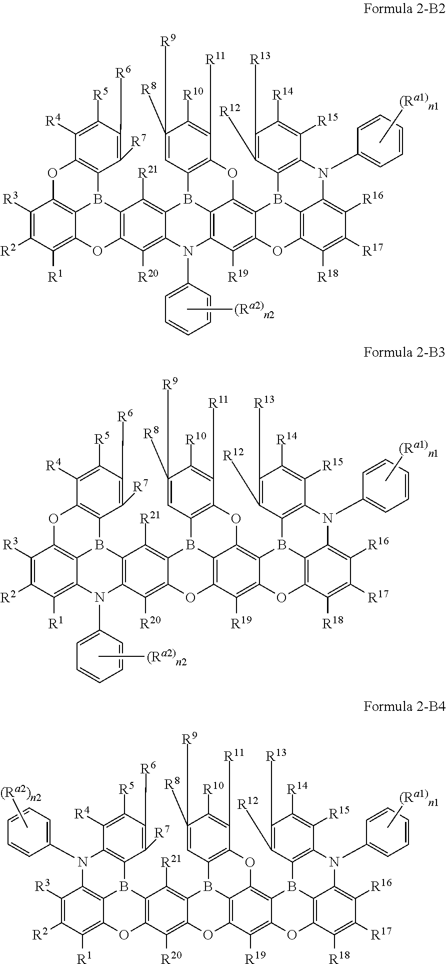 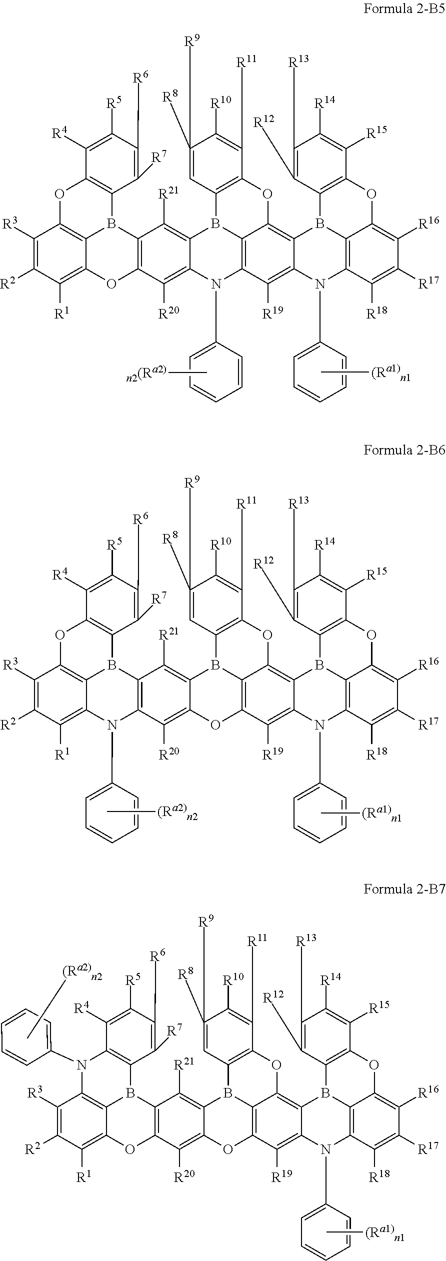 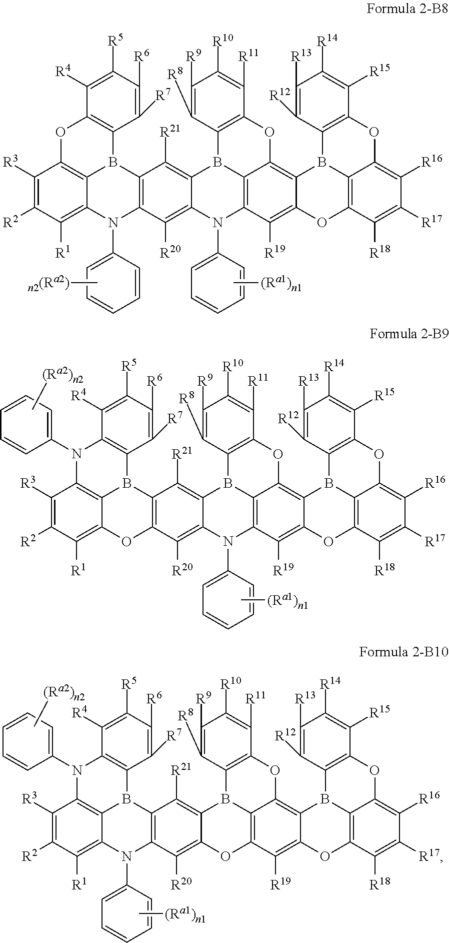
in Formulas 2-A1 to 2-A5 and Formulas 2-B1 to 2-B10,
n1 and n2 being each independently an integer of 0 to 5,
R^{a1} and R^{a2} being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
R¹ to R²¹ being each the same as defined in Formula 2.

7. The light emitting element of claim 5, wherein the first compound represented by Formula 2 is represented by any one selected from among Formulas 2-C1 to 2-C10 and Formulas 2-D1 to 2-D5: 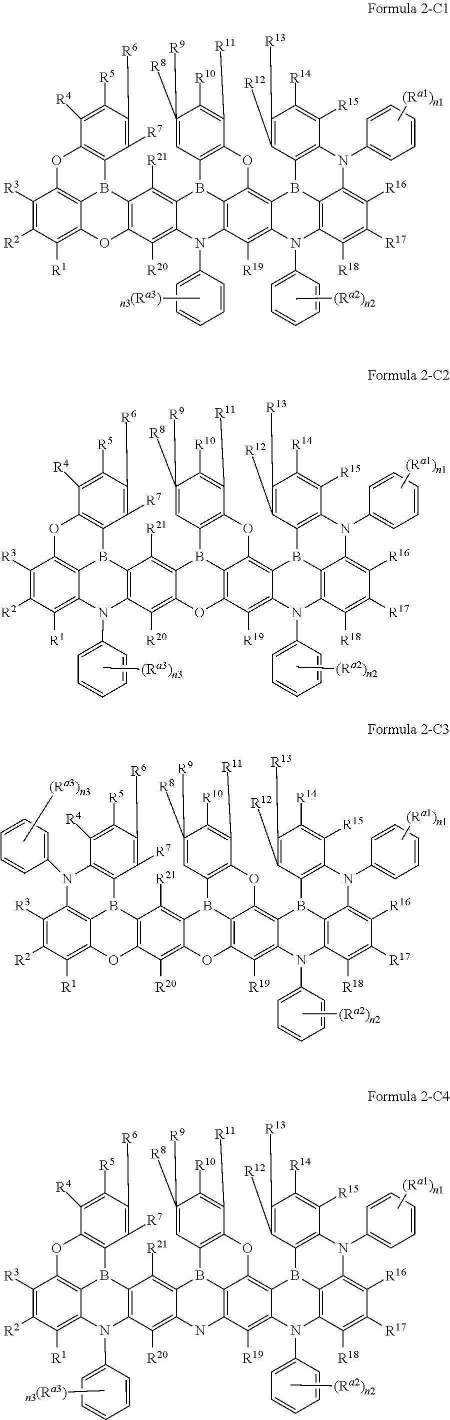 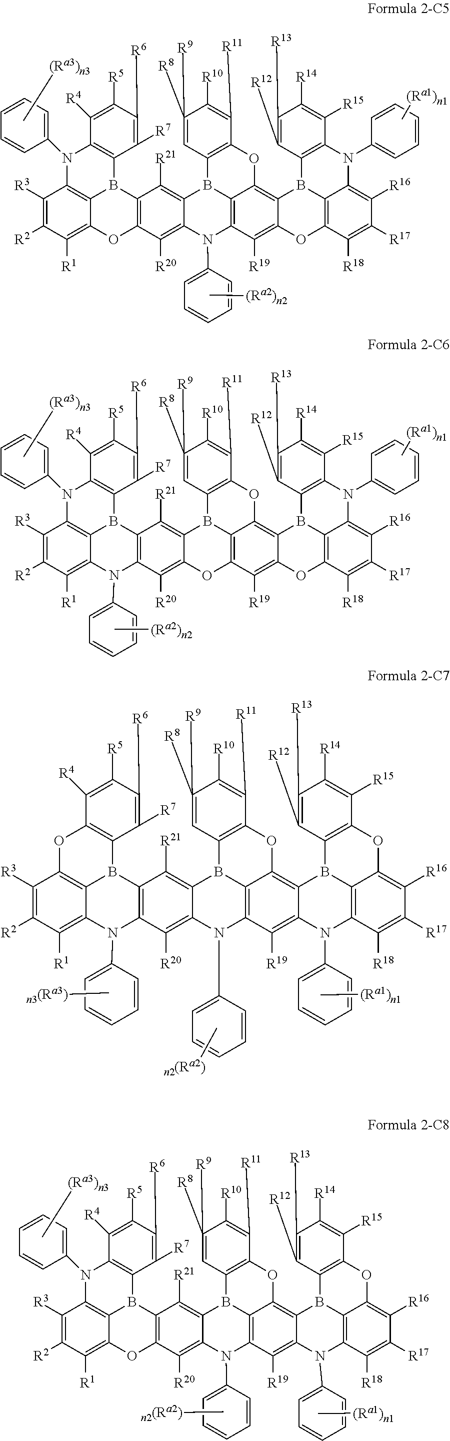 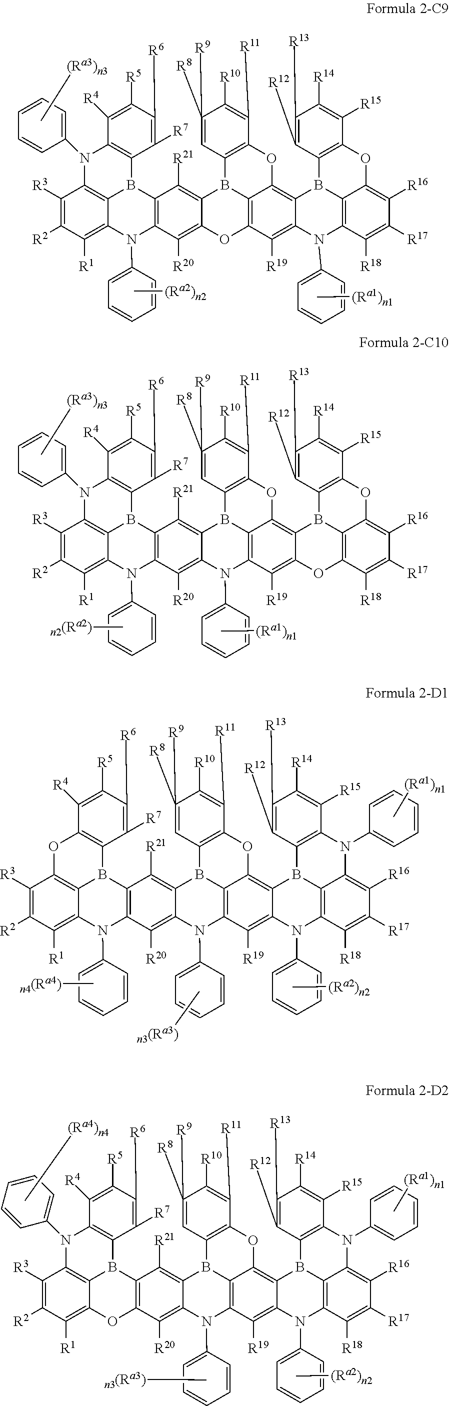 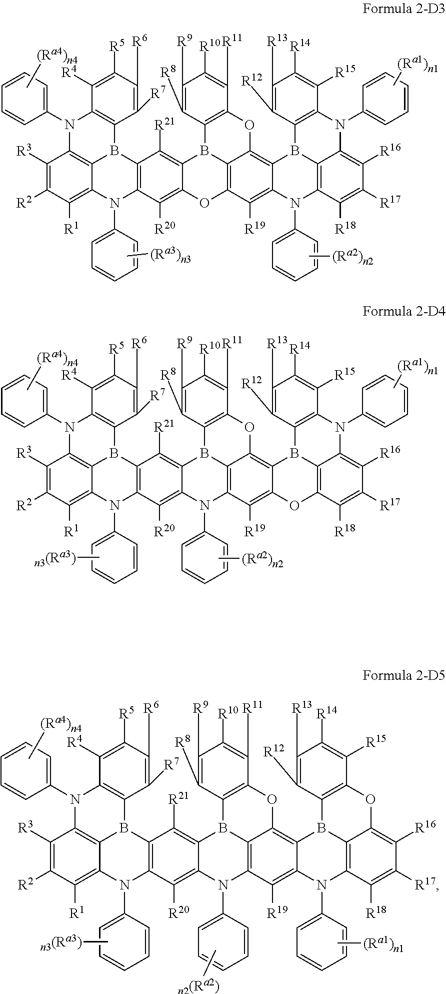
in Formulas 2-C1 to 2-C10 and Formulas 2-D1 to 2-D5,
n1 to n4 being each independently an integer of 0 to 5,
R^{a1} to R^{a4} being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
R¹ to R²¹ being each the same as defined in Formula 2.

8. The light emitting element of claim 5, wherein in Formula 2, the at least one selected from among R¹ to R²¹ is a substituted or unsubstituted t-butyl group, a substituted or unsubstituted phenyl group, or a substituted or unsubstituted carbazole group.

9. The light emitting element of claim 5, wherein in Formula 2, the at least one selected from among R¹ to R²¹ is represented by any one selected from among R-1 to R-7: 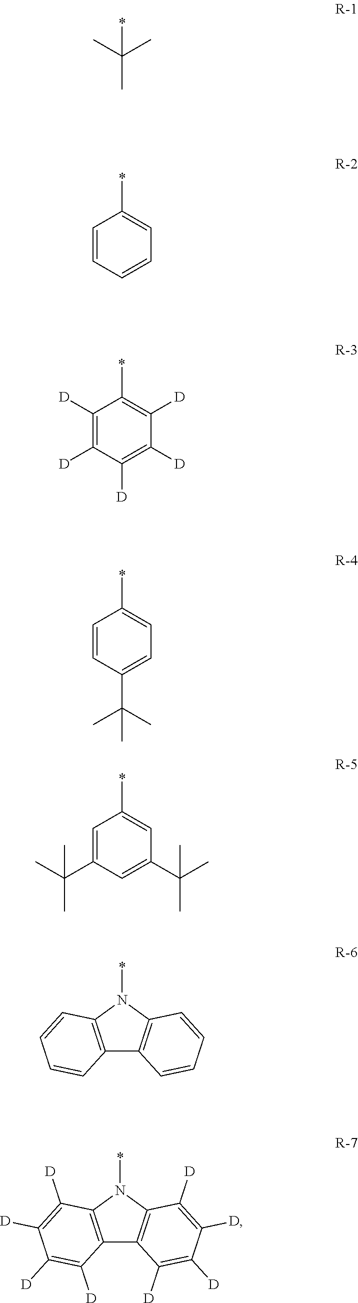
in R-3 and R-7, D being deuterium.

10. The light emitting element of claim 1, wherein the first compound is any one selected from among compounds from Compound Group 1: 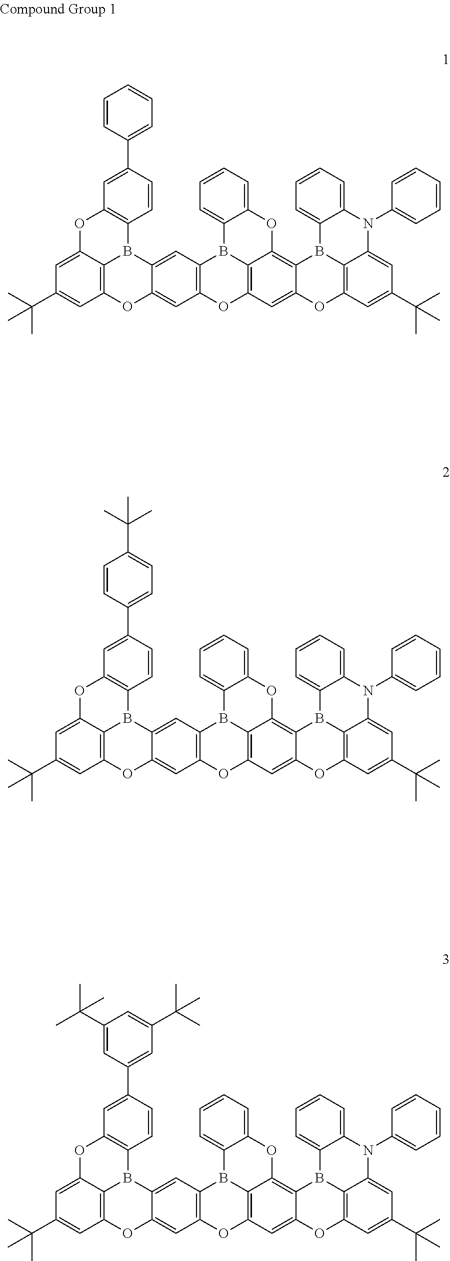 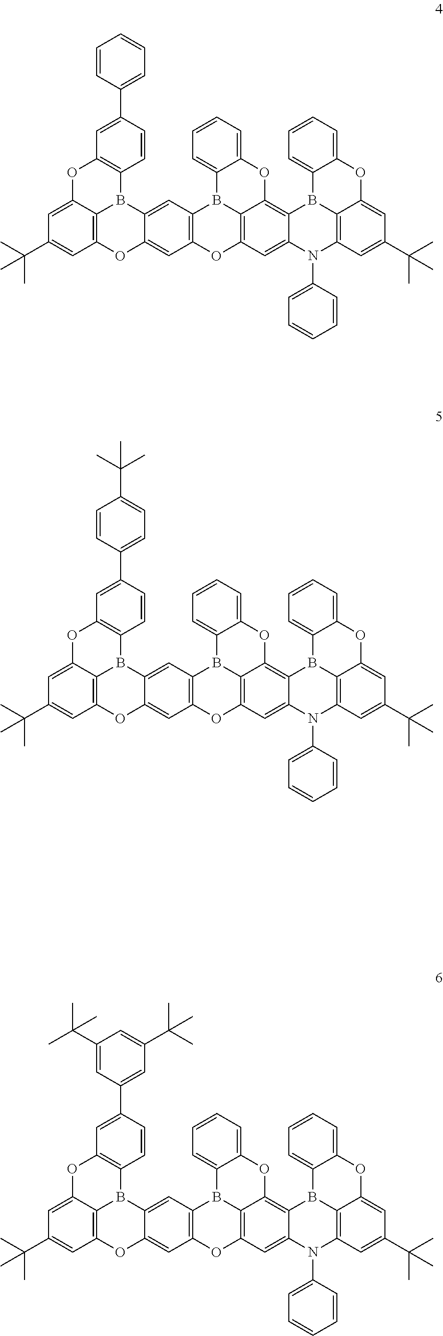 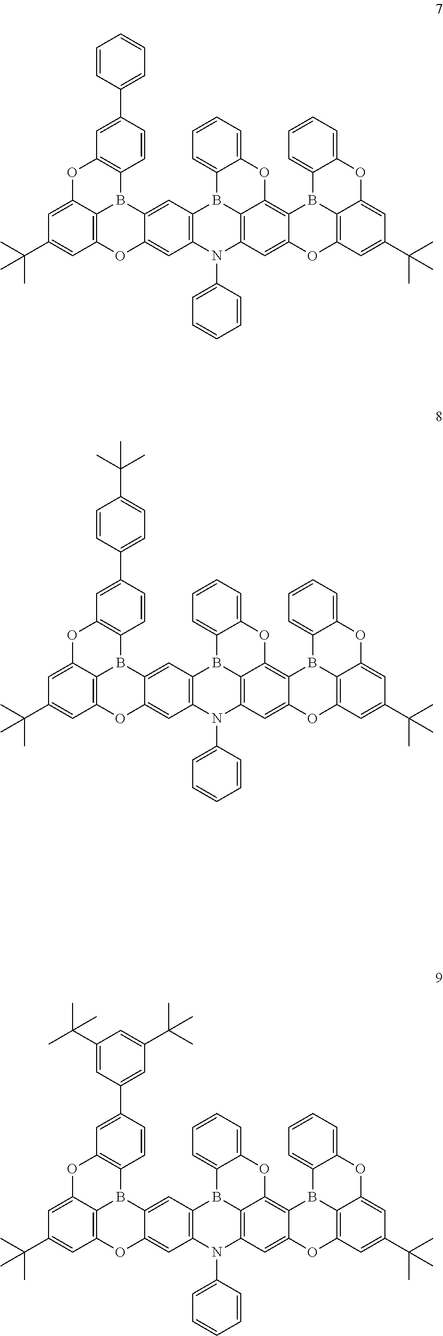 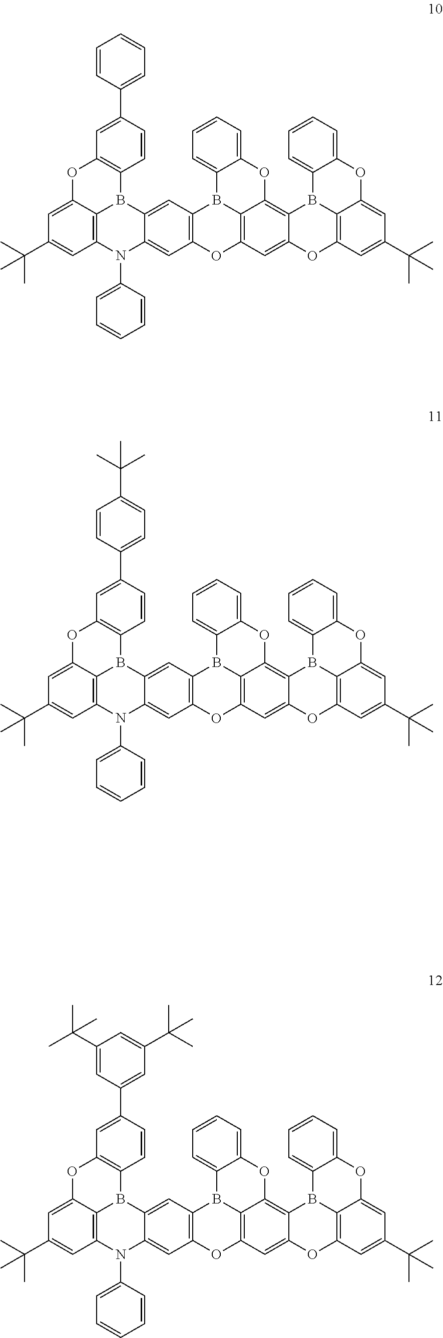 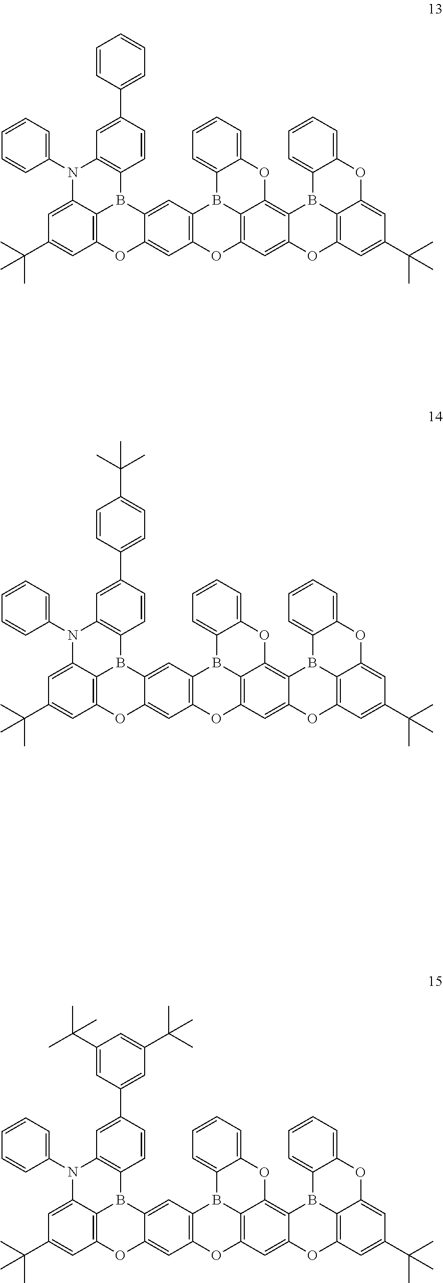 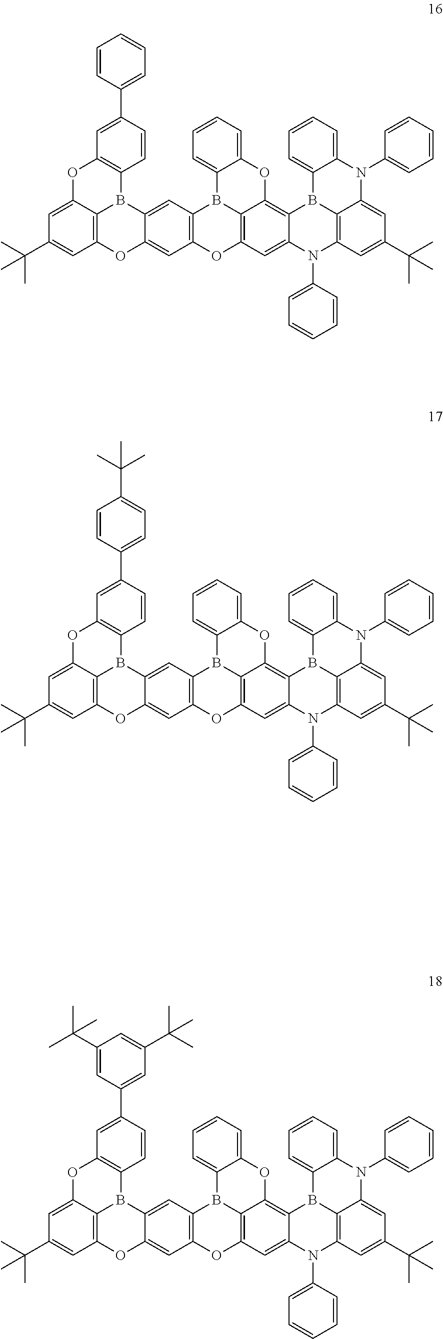 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1] 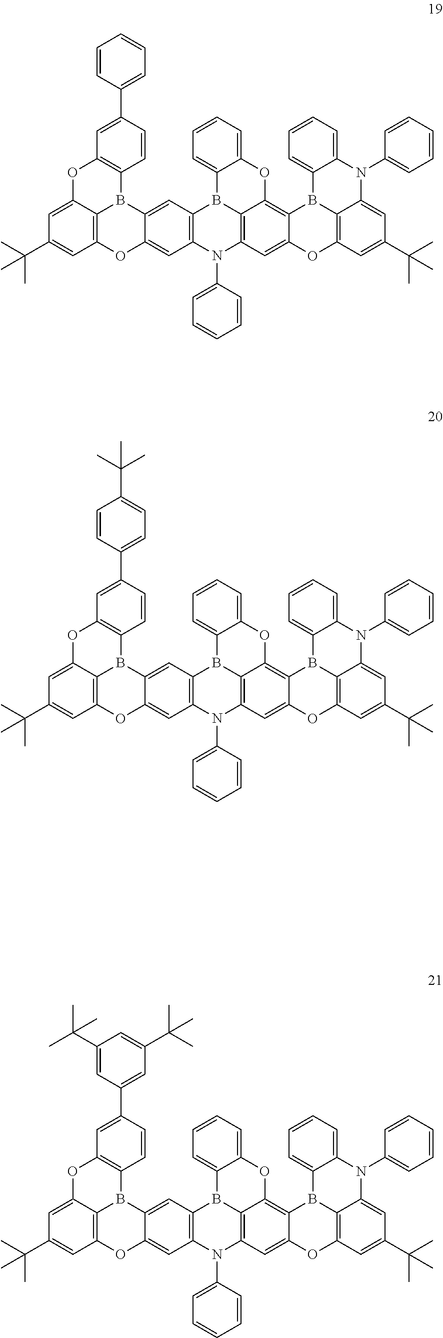 [SMILES: CC(C)(C)c1cc2c3c(c1)Oc1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1] 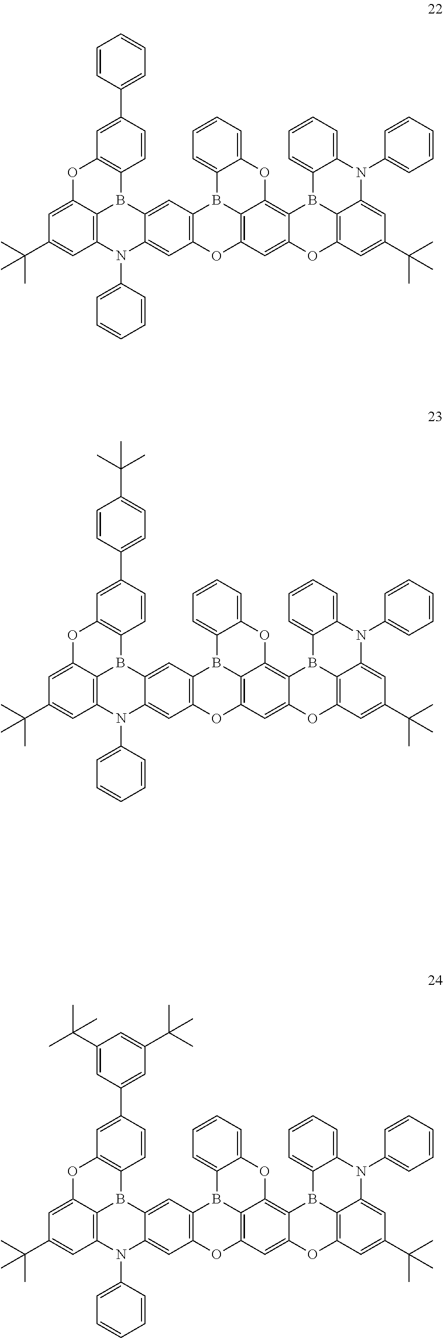 [SMILES: CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)O1)O4 ; CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1] 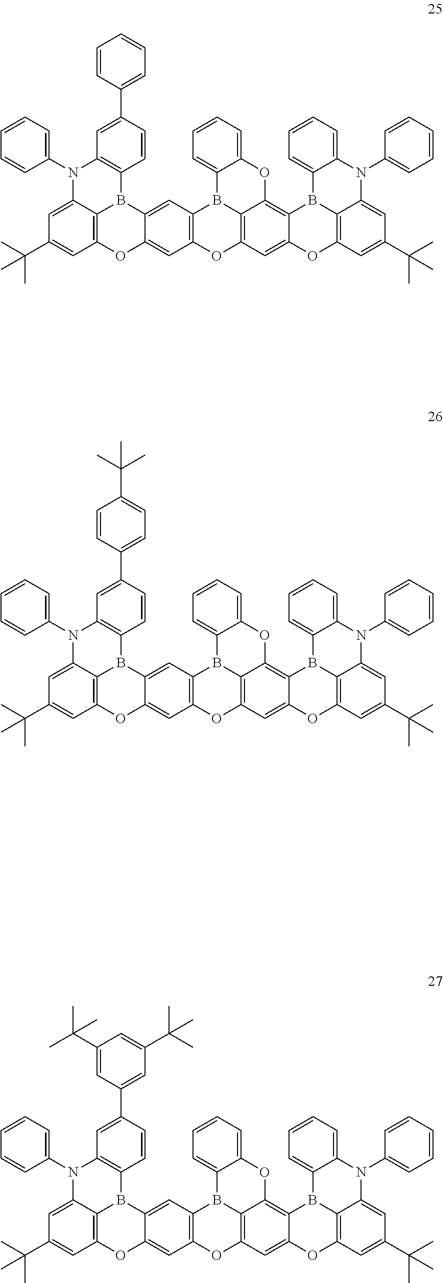 [SMILES: CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc(C(C)(C)C)c1] 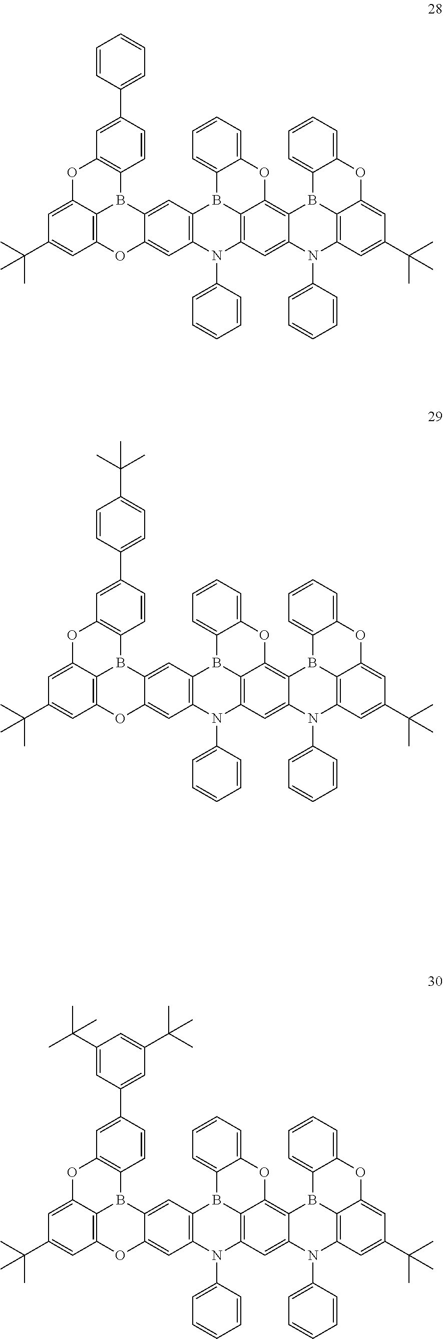 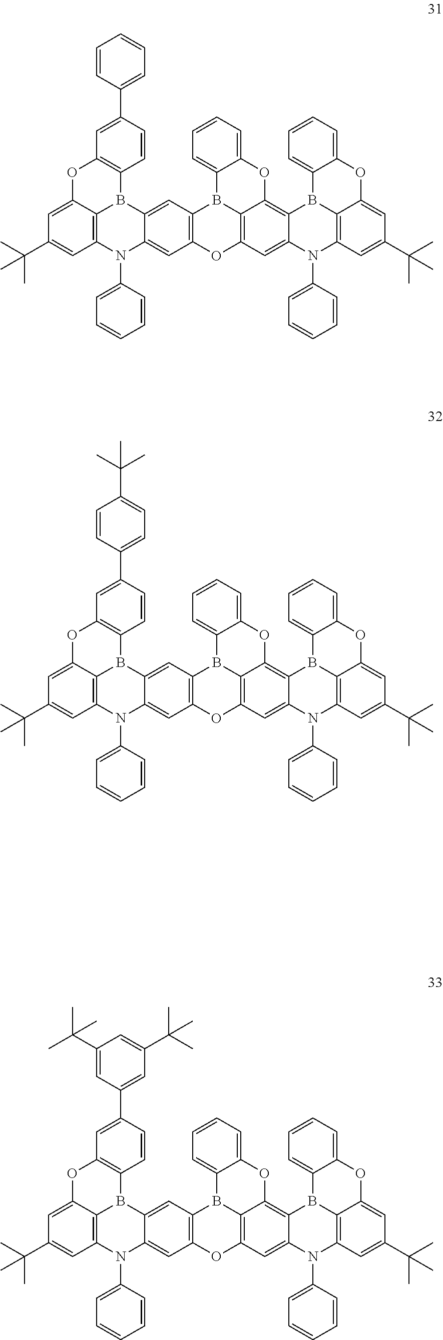 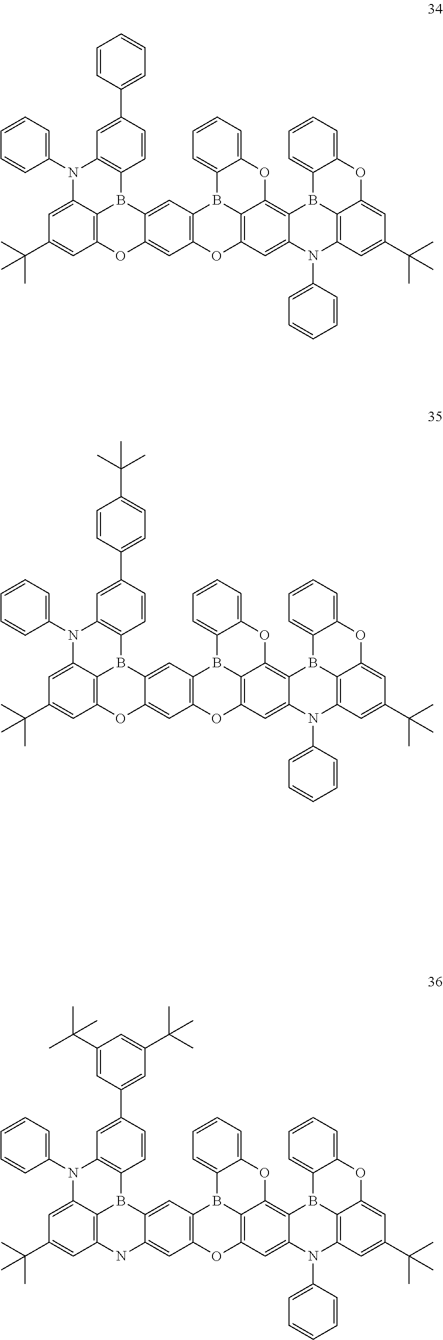 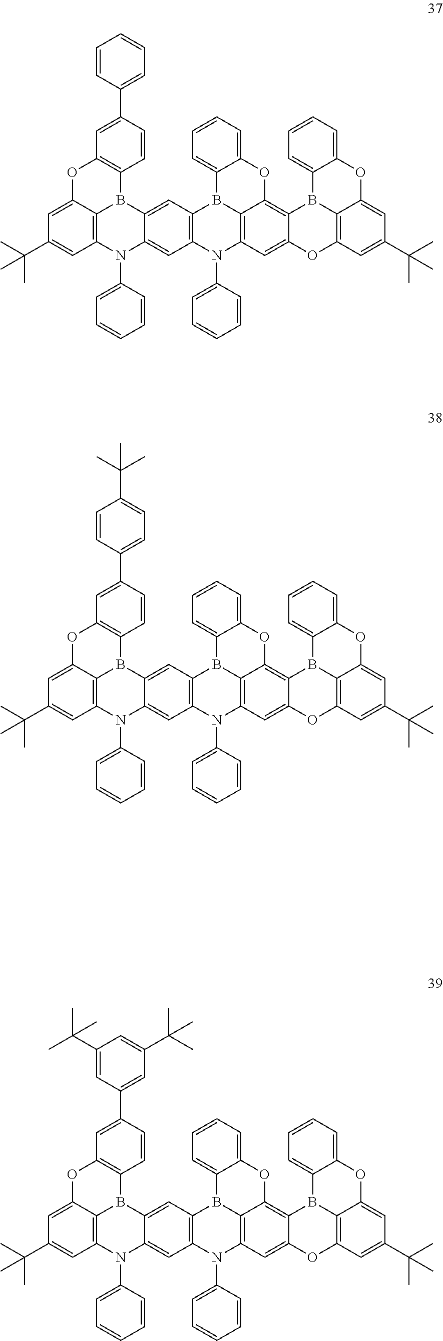 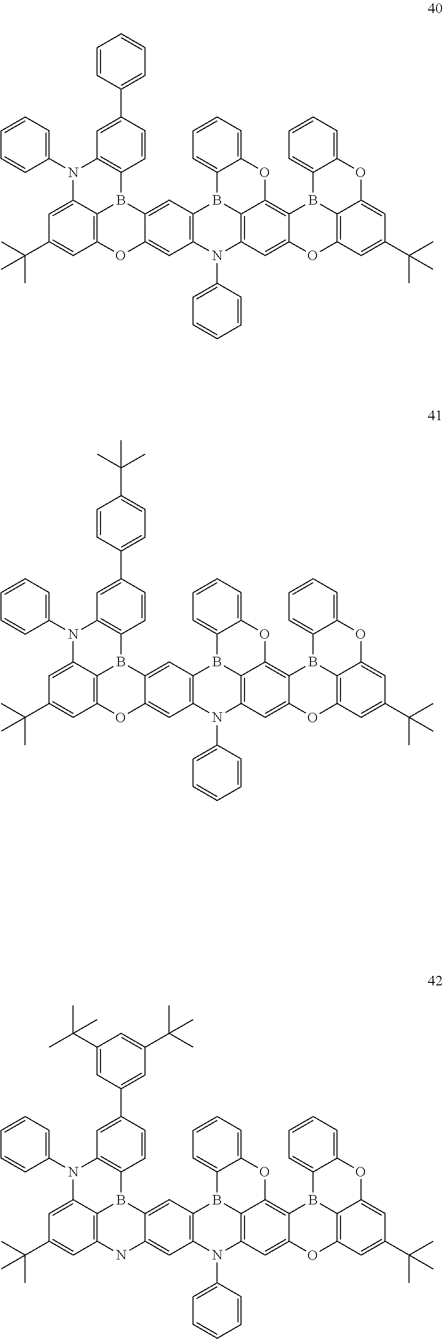 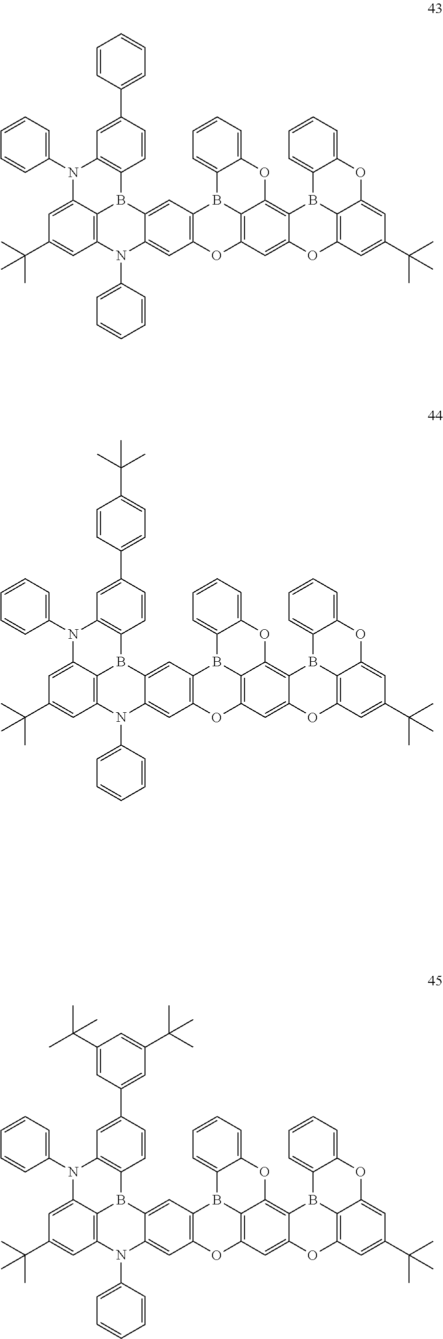 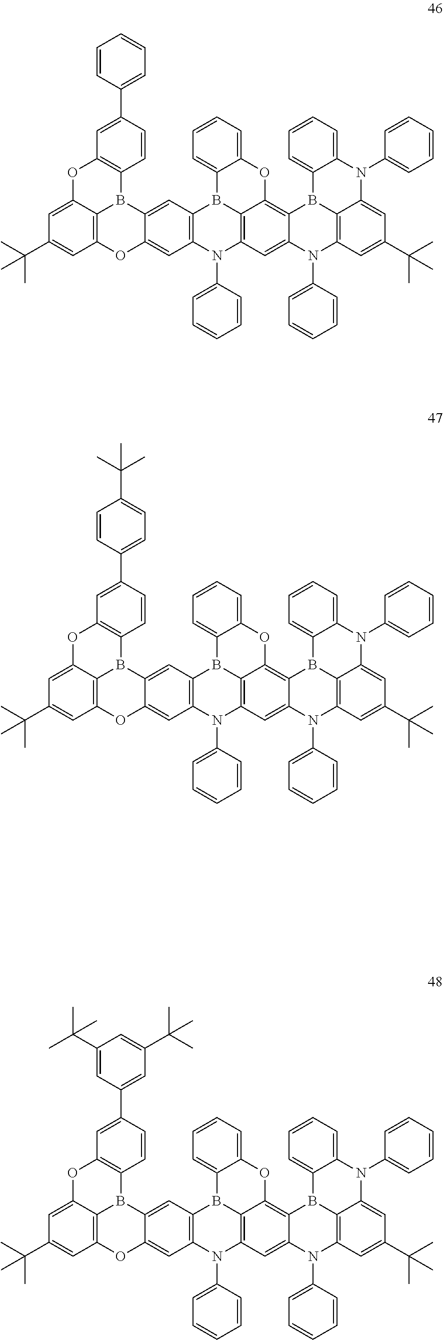 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1] 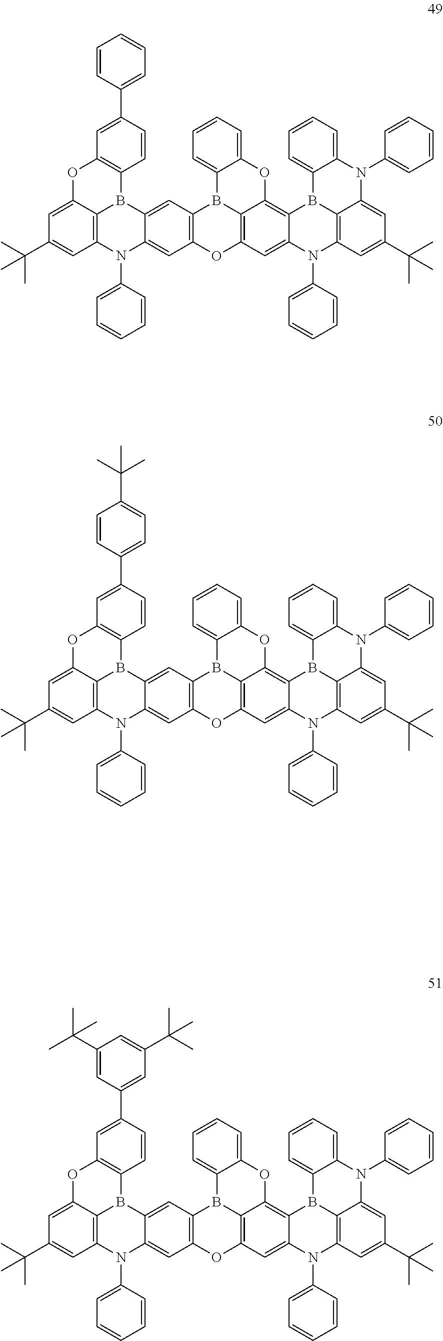 [SMILES: CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc(C(C)(C)C)c1] 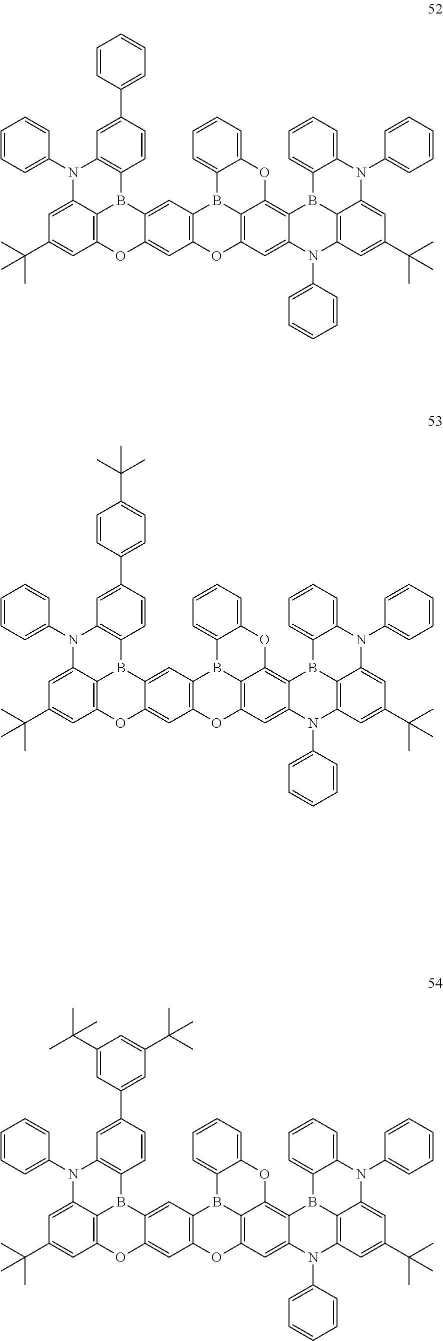 [SMILES: CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)N2c1ccccc1 ; CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1] 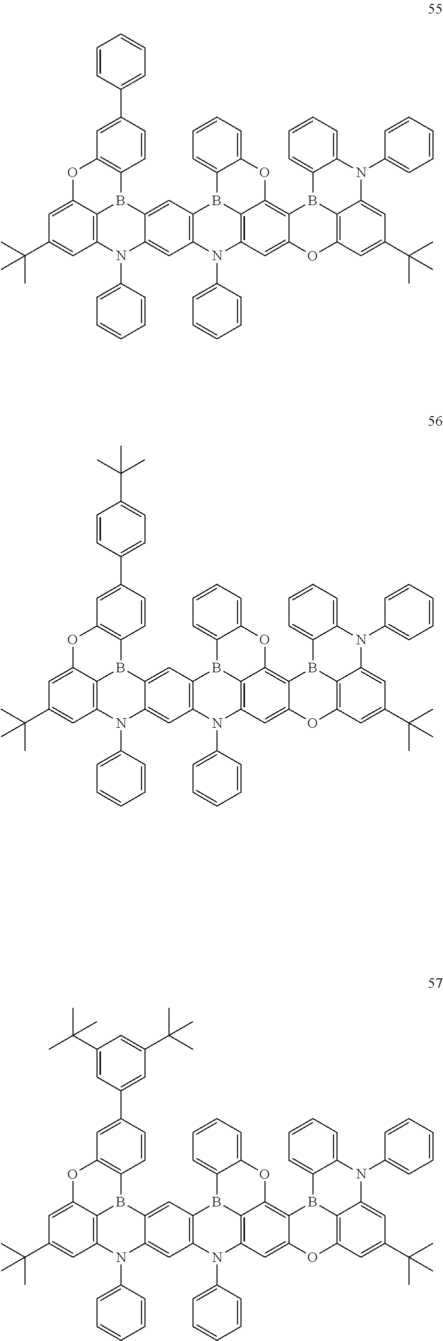 [SMILES: CC(C)(C)c1cc2c3c(c1)N(c1ccccc1)c1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1] 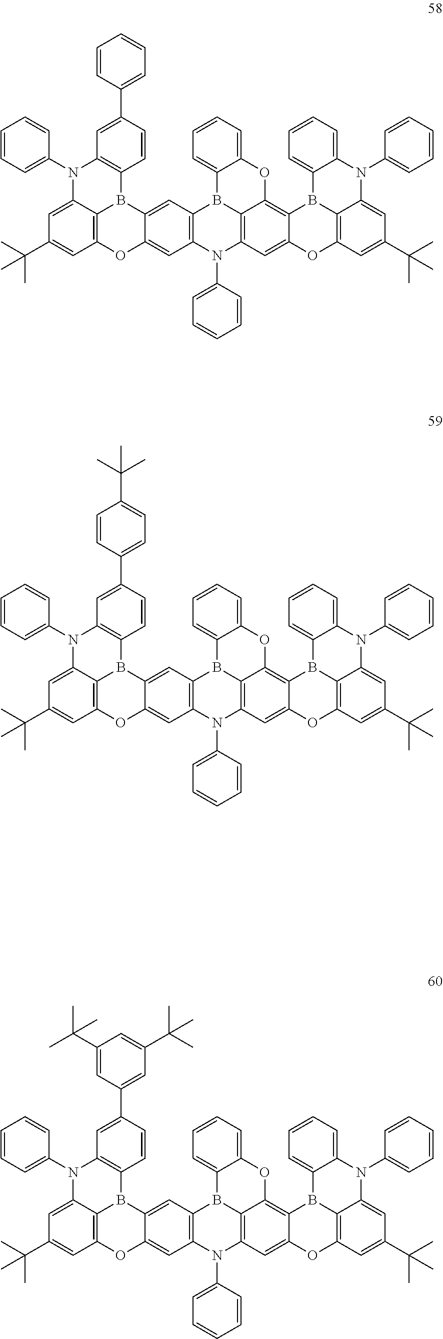 [SMILES: CC(C)(C)c1cc2c3c(c1)N(c1ccccc1)c1cc(-c4ccccc4)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1] 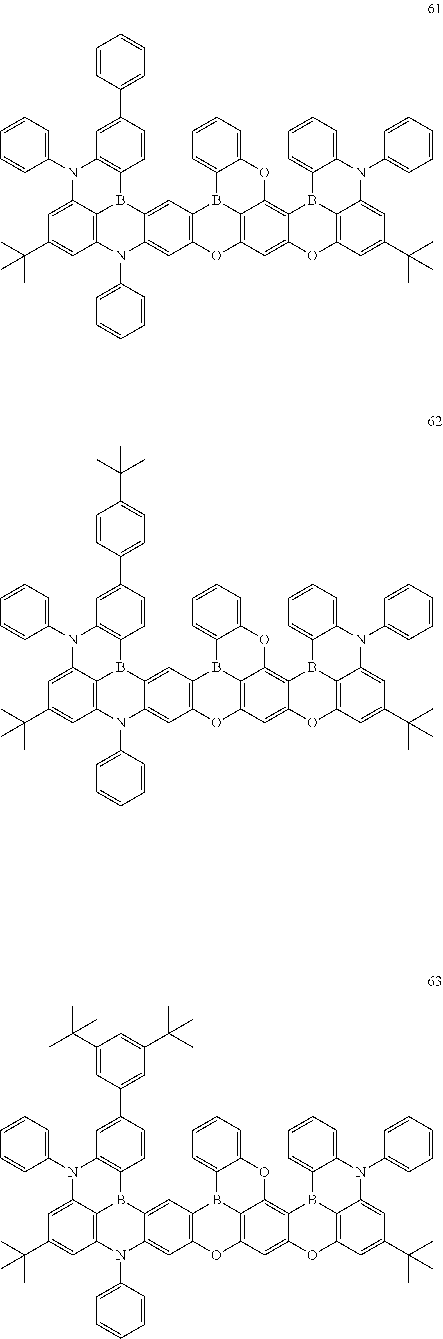 [SMILES: CC(C)(C)c1cc2c3c(c1)N(c1ccccc1)c1ccccc1B3c1c(cc3c4c1Oc1ccccc1B4c1cc4c(cc1O3)N(c1ccccc1)c1cc(C(C)(C)C)cc3c1B4c1ccc(-c4ccccc4)cc1N3c1ccccc1)O2 ; CC(C)(C)c1ccc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1] 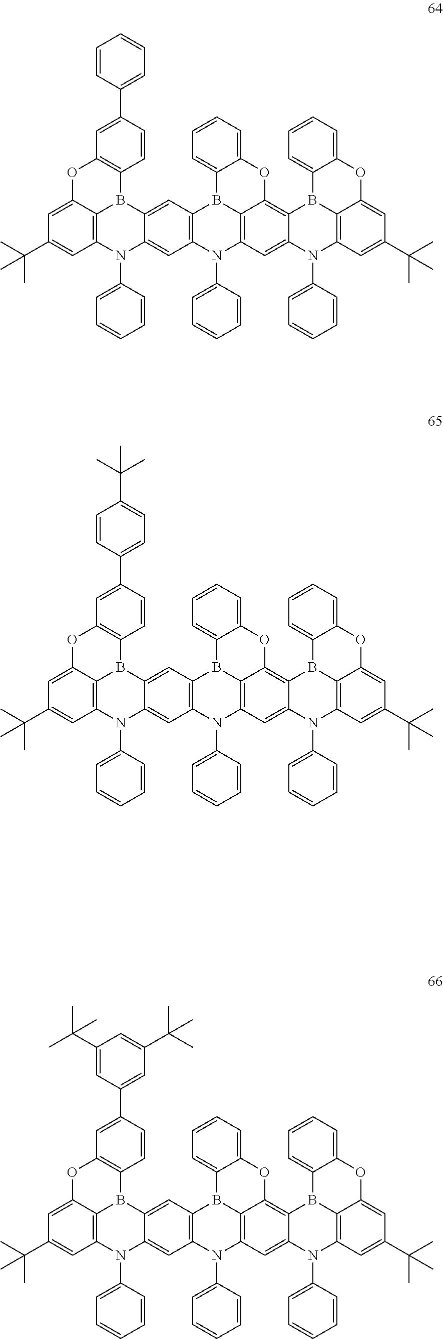 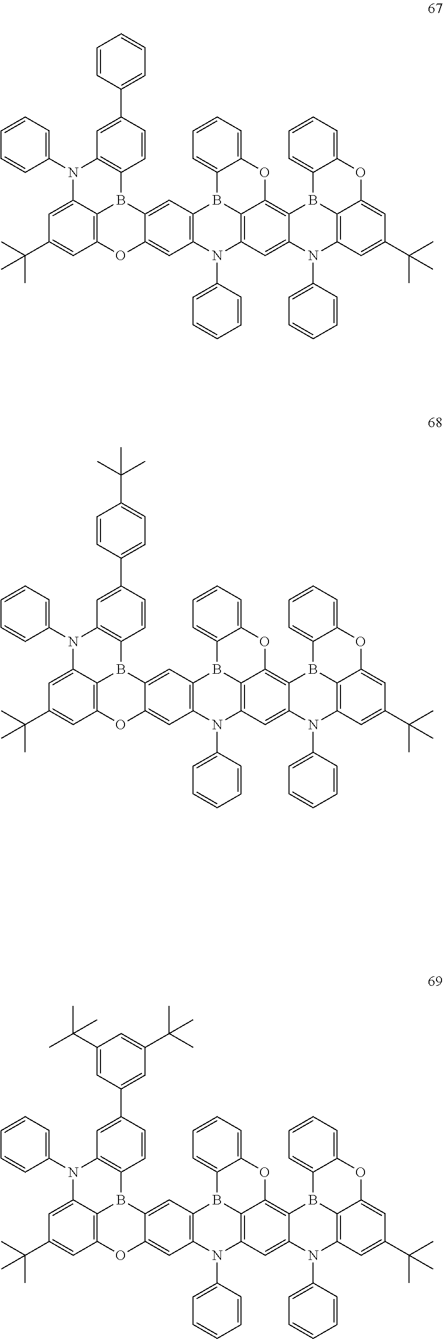 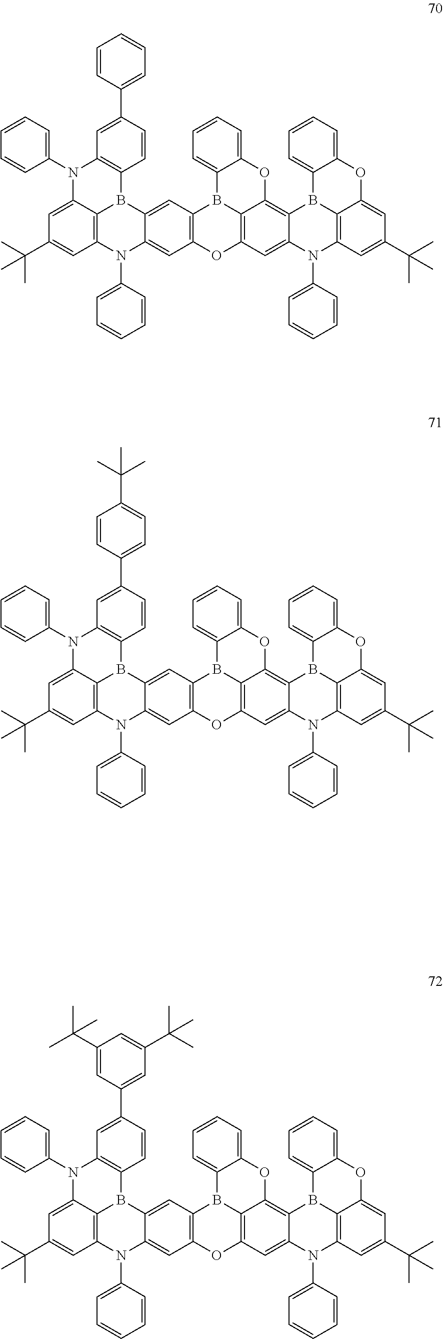 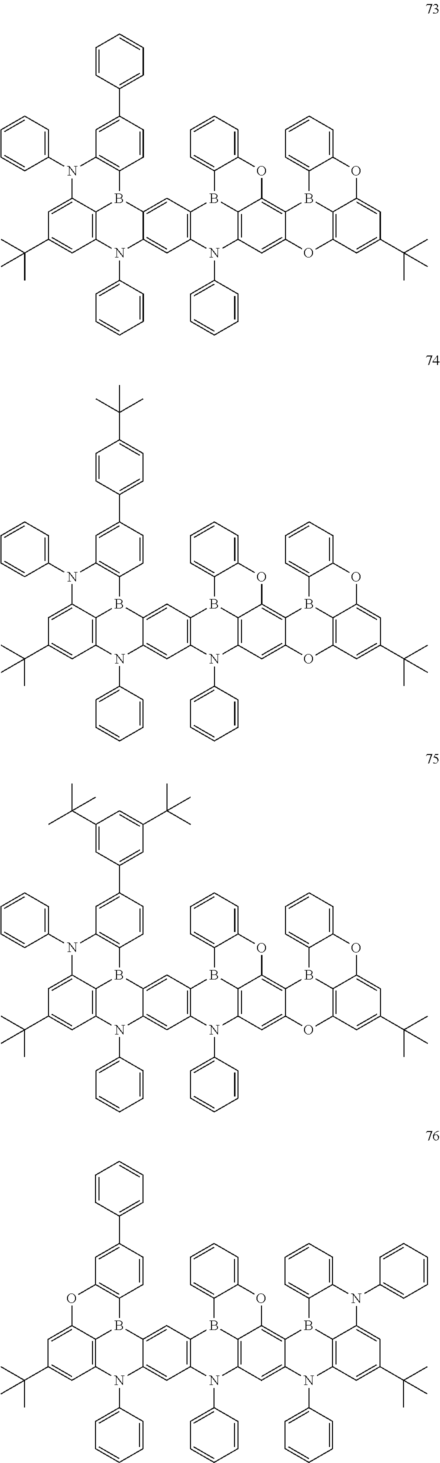 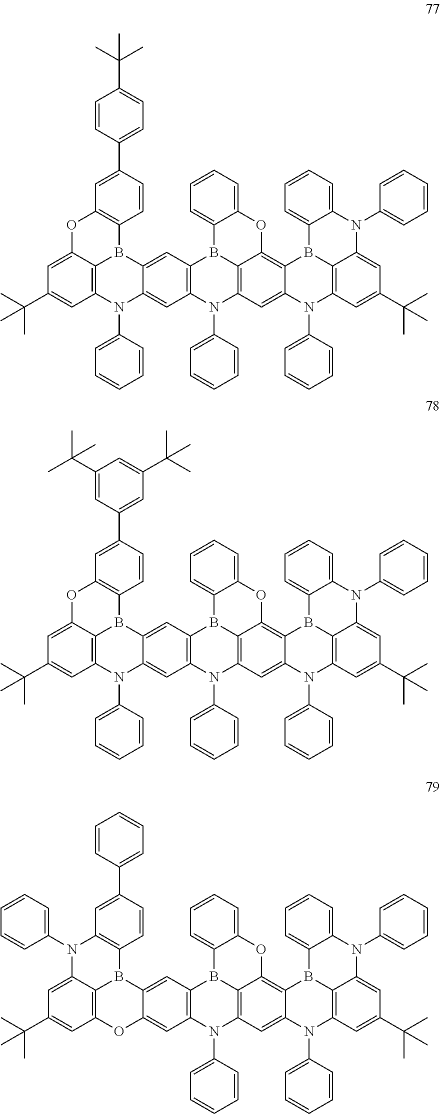 [SMILES: CC(C)(C)c1ccc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1cc(-c4ccccc4)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)N2c1ccccc1] 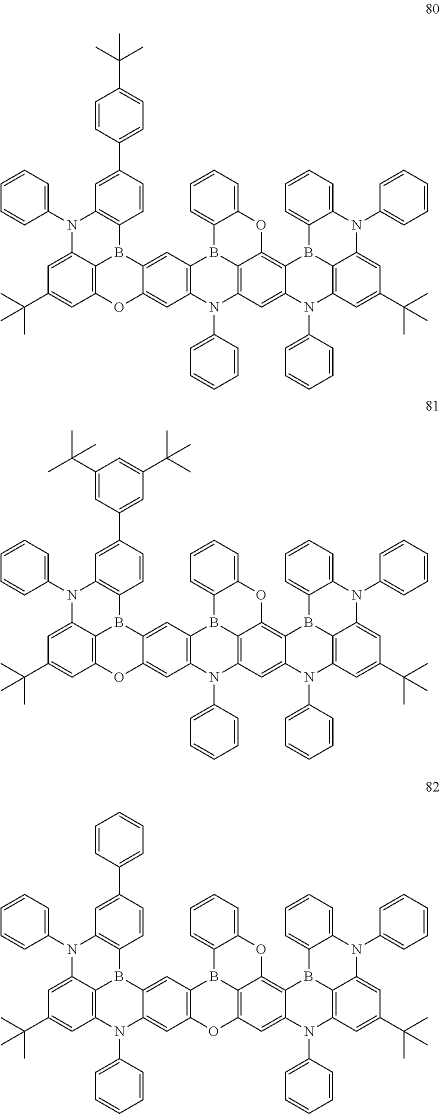 [SMILES: CC(C)(C)c1ccc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1cc4c(cc1B3c1ccc(-c3ccccc3)cc1N2c1ccccc1)B1c2ccccc2Oc2c1c(cc1c2B2c3ccccc3N(c3ccccc3)c3cc(C(C)(C)C)cc(c32)N1c1ccccc1)O4] 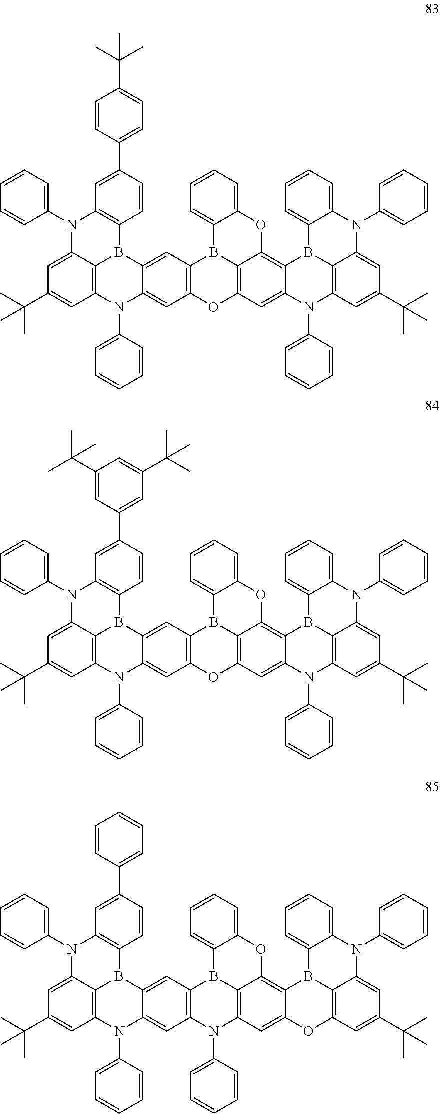 [SMILES: CC(C)(C)c1ccc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1ccccc1B3c1c(cc3c4c1Oc1ccccc1B4c1cc4c(cc1N3c1ccccc1)N(c1ccccc1)c1cc(C(C)(C)C)cc3c1B4c1ccc(-c4ccccc4)cc1N3c1ccccc1)O2] 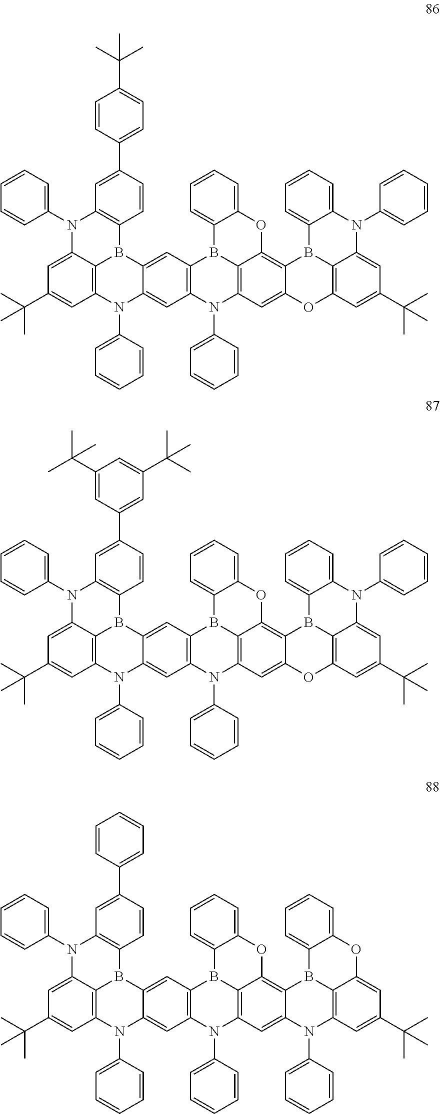 [SMILES: CC(C)(C)c1ccc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1 ; CC(C)(C)c1cc2c3c(c1)N(c1ccccc1)c1cc4c5c(c1B3c1ccccc1O2)Oc1ccccc1B5c1cc2c(cc1N4c1ccccc1)N(c1ccccc1)c1cc(C(C)(C)C)cc3c1B2c1ccc(-c2ccccc2)cc1N3c1ccccc1] 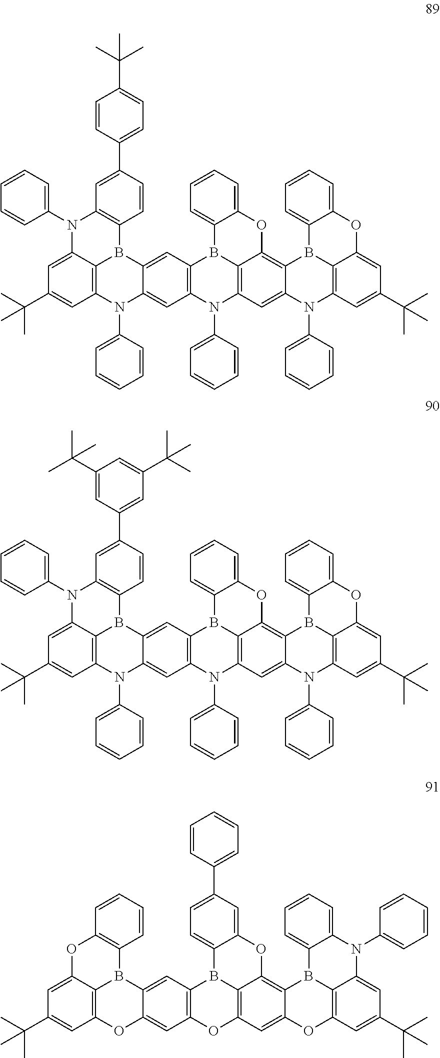 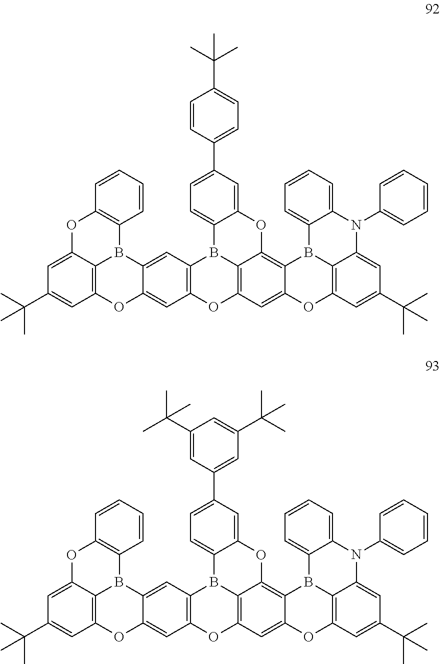 [SMILES: CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)O5)cc(C(C)(C)C)c1] 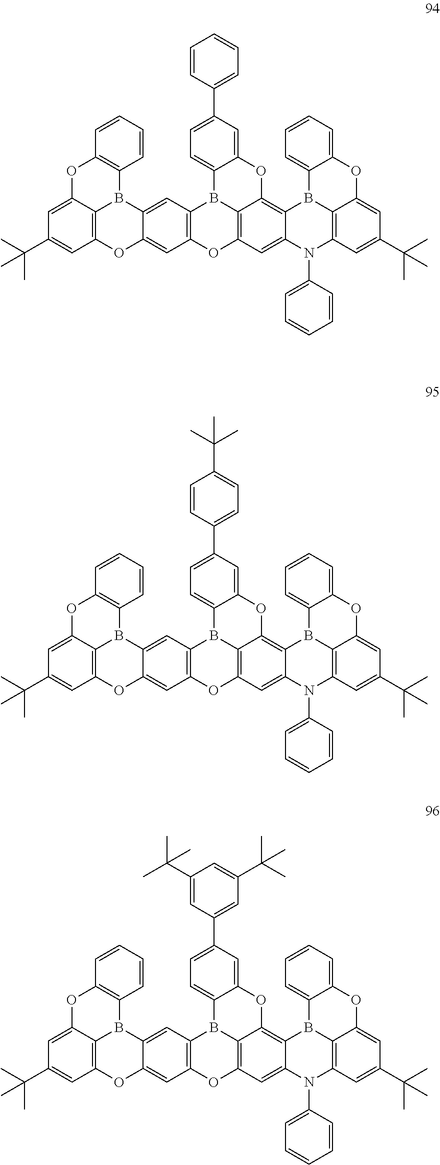 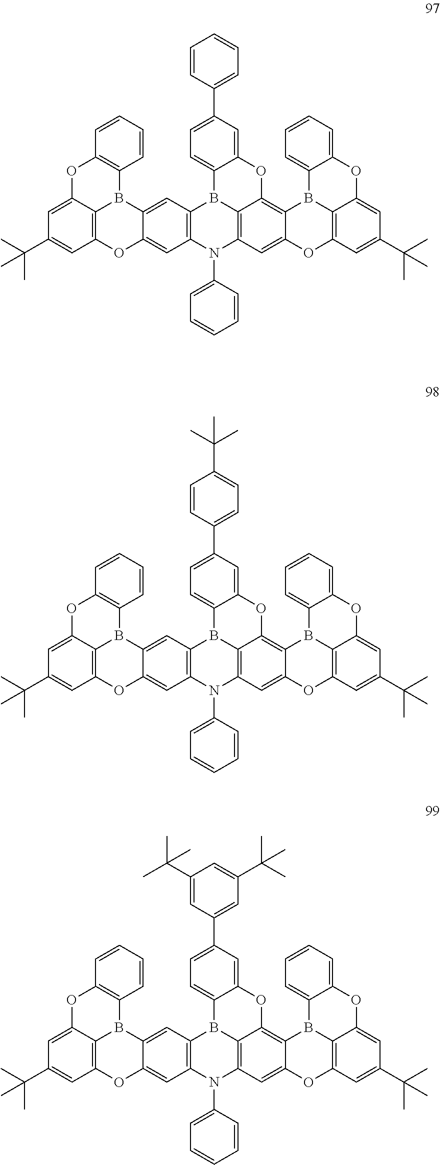 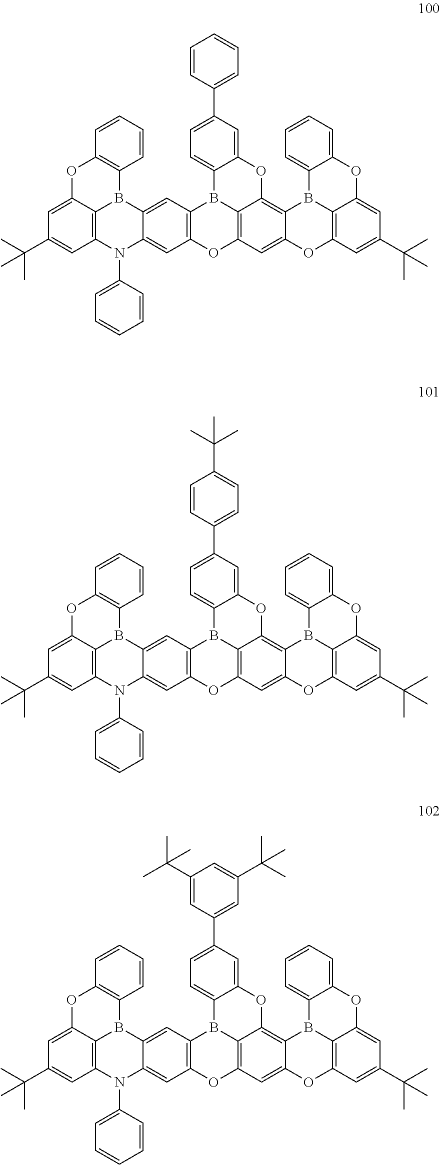 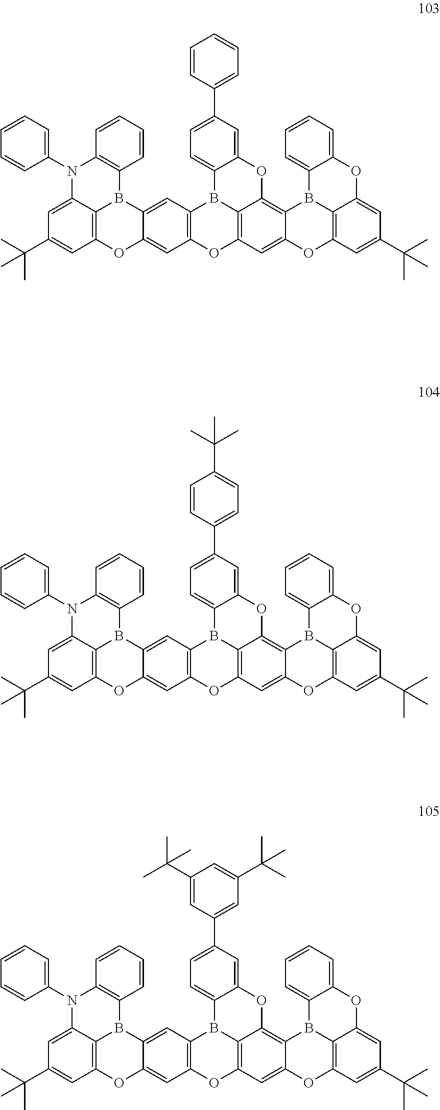 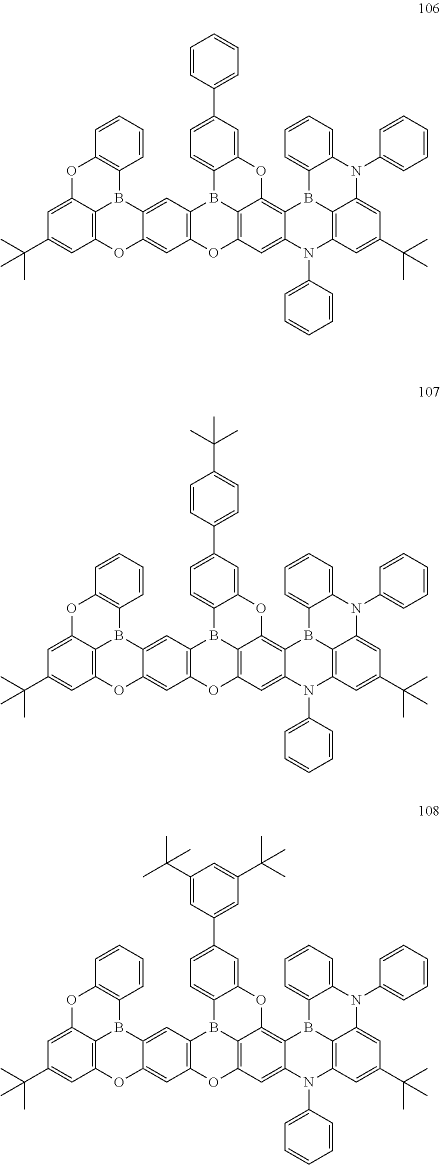 [SMILES: CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3Oc3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3Oc3cc(C(C)(C)C)cc(c32)O5)cc(C(C)(C)C)c1] 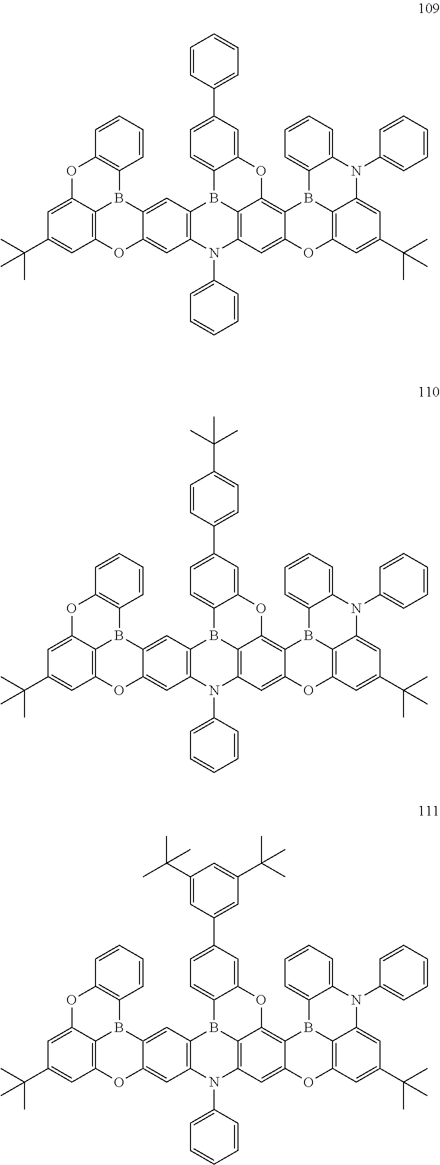 [SMILES: CC(C)(C)c1cc2c3c(c1)Oc1cc4c(cc1B3c1ccccc1O2)B1c2ccc(-c3ccccc3)cc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2c4c(cc5c2B3c2cc3c(cc2N5c2ccccc2)Oc2cc(C(C)(C)C)cc5c2B3c2ccccc2O5)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)Oc2cc(C(C)(C)C)cc5c2B3c2ccccc2O5)Oc2cc(C(C)(C)C)cc3c2B4c2ccccc2N3c2ccccc2)cc(C(C)(C)C)c1] 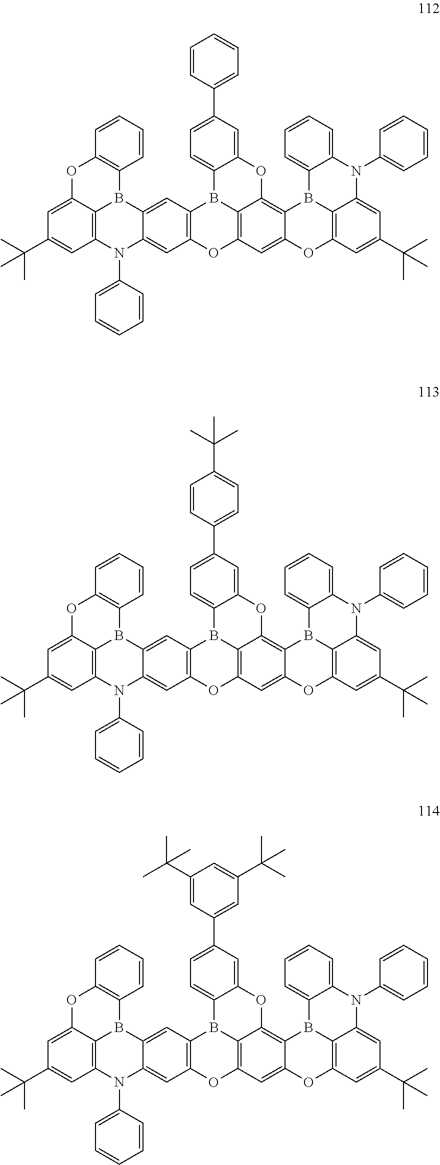 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)O1)O4 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)N5c2ccccc2)cc(C(C)(C)C)c1] 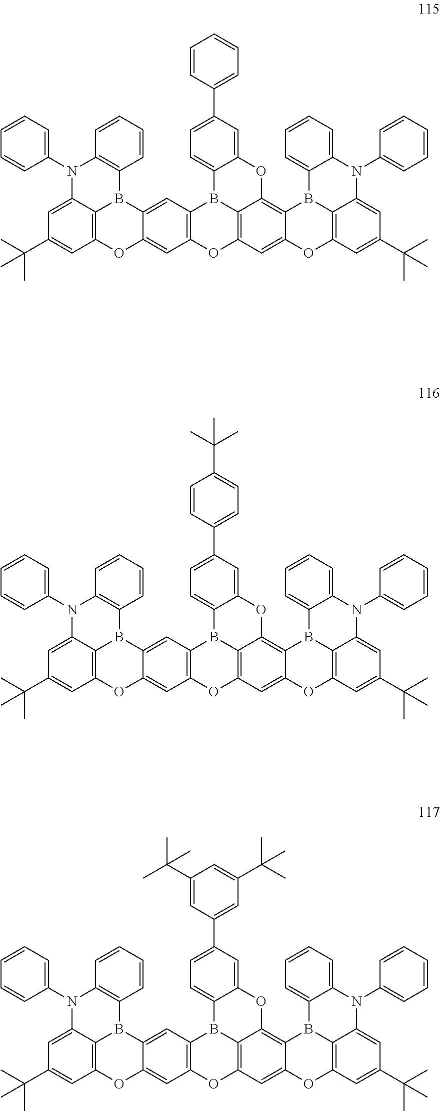 [SMILES: CC(C)(C)c1cc2c3c(c1)N(c1ccccc1)c1ccccc1B3c1cc3c(cc1O2)Oc1cc2c(c4c1B3c1ccc(-c3ccccc3)cc1O4)B1c3ccccc3N(c3ccccc3)c3cc(C(C)(C)C)cc(c31)O2 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)O5)cc(C(C)(C)C)c1] 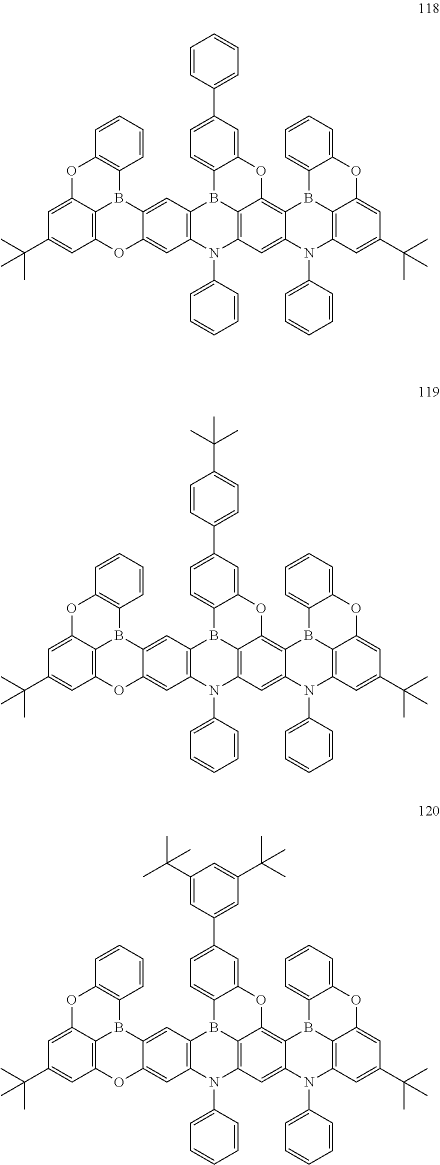 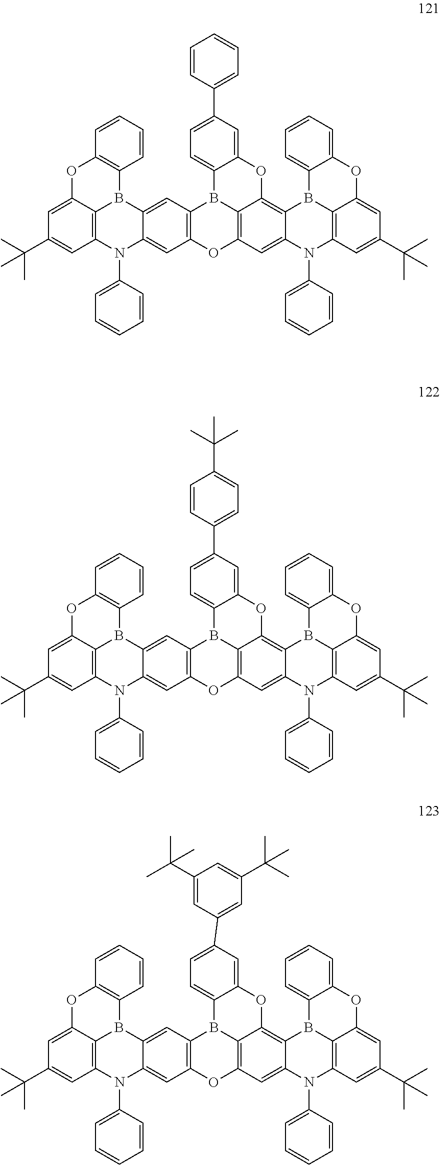 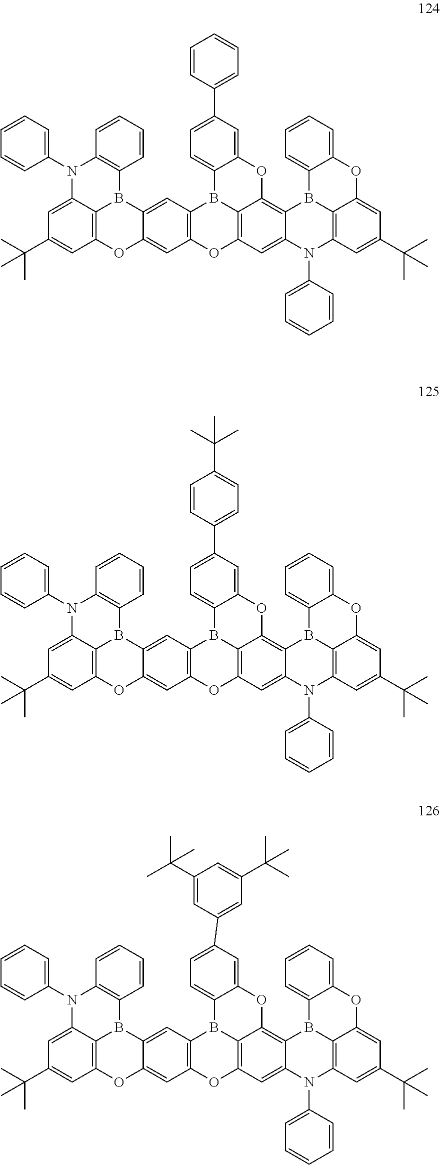 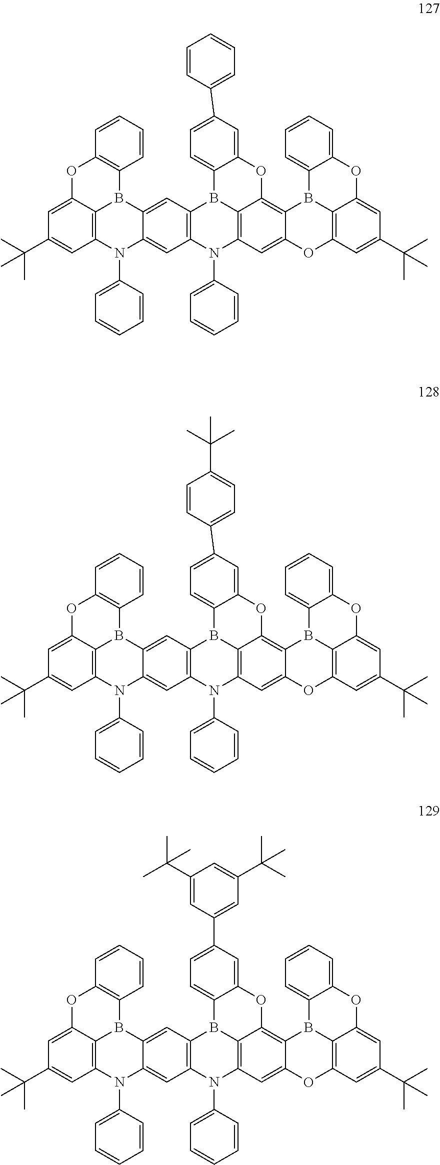 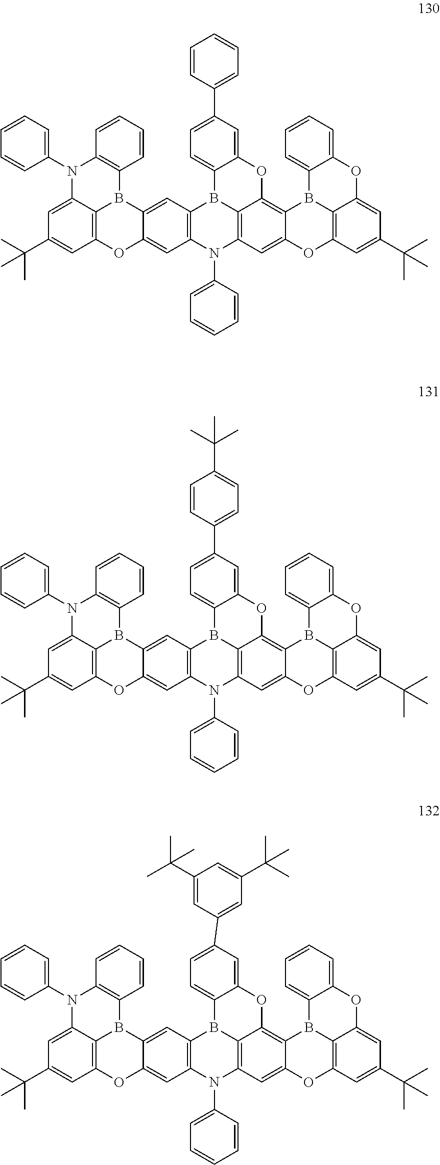 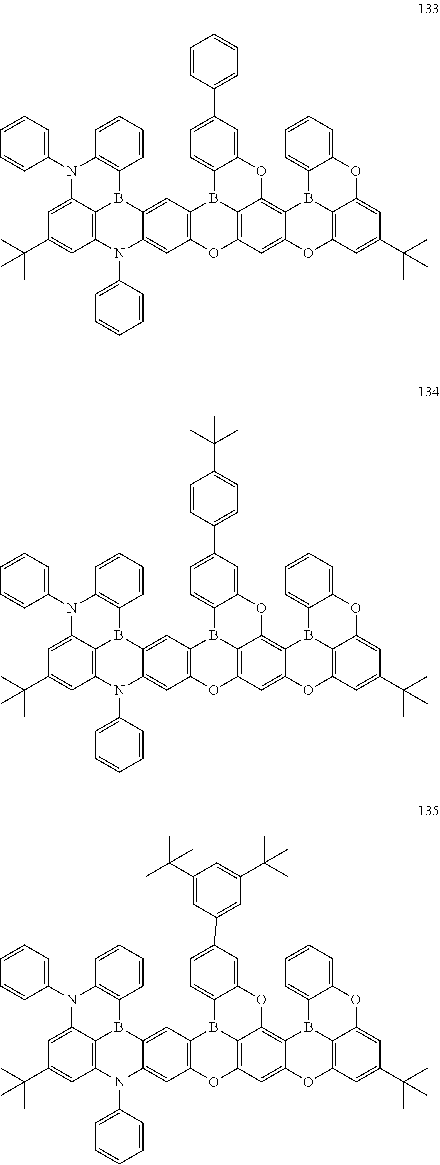 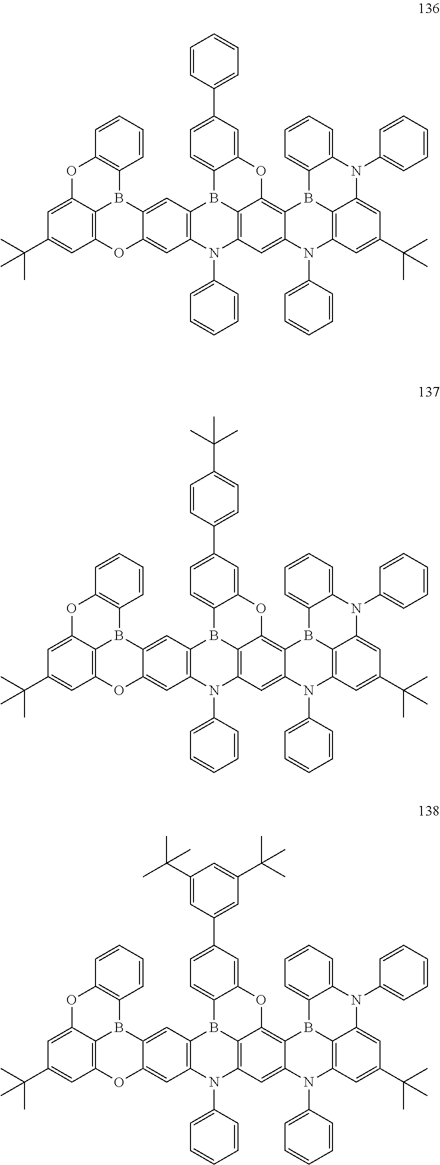 [SMILES: CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)O5)cc(C(C)(C)C)c1] 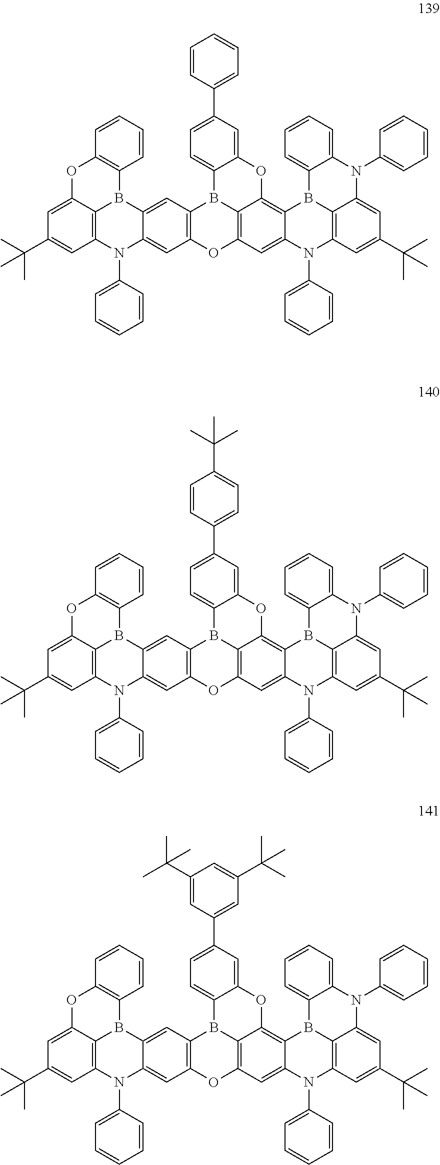 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3Oc3cc(C(C)(C)C)cc(c32)N5c2ccccc2)cc(C(C)(C)C)c1] 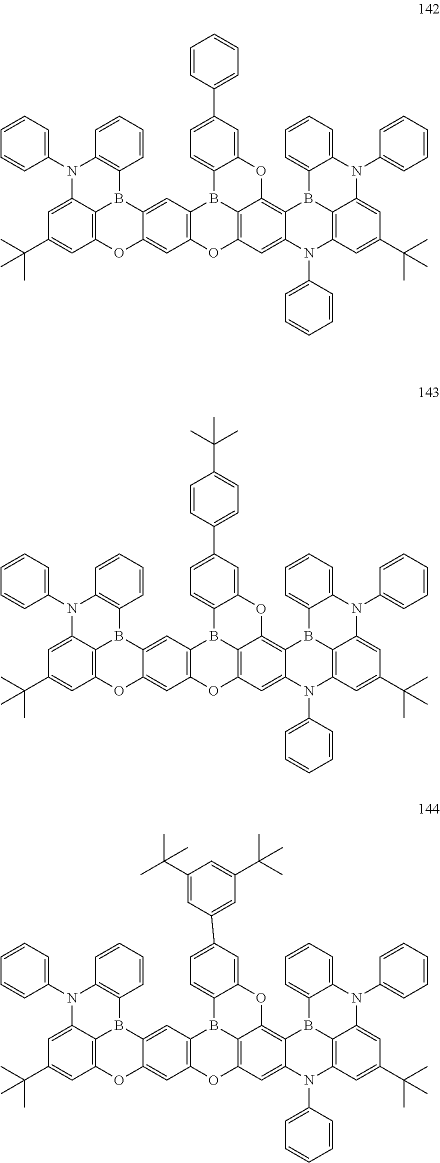 [SMILES: CC(C)(C)c1cc2c3c(c1)N(c1ccccc1)c1ccccc1B3c1cc3c(cc1O2)Oc1cc2c(c4c1B3c1ccc(-c3ccccc3)cc1O4)B1c3ccccc3N(c3ccccc3)c3cc(C(C)(C)C)cc(c31)N2c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)O5)cc(C(C)(C)C)c1] 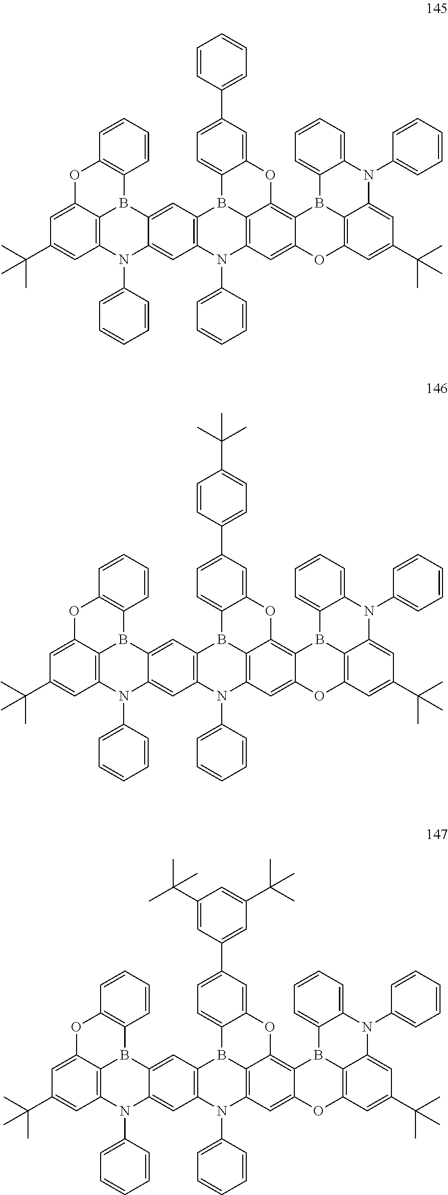 [SMILES: CC(C)(C)c1cc2c3c(c1)N(c1ccccc1)c1cc4c(cc1B3c1ccccc1O2)B1c2ccc(-c3ccccc3)cc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc(C(C)(C)C)c1] 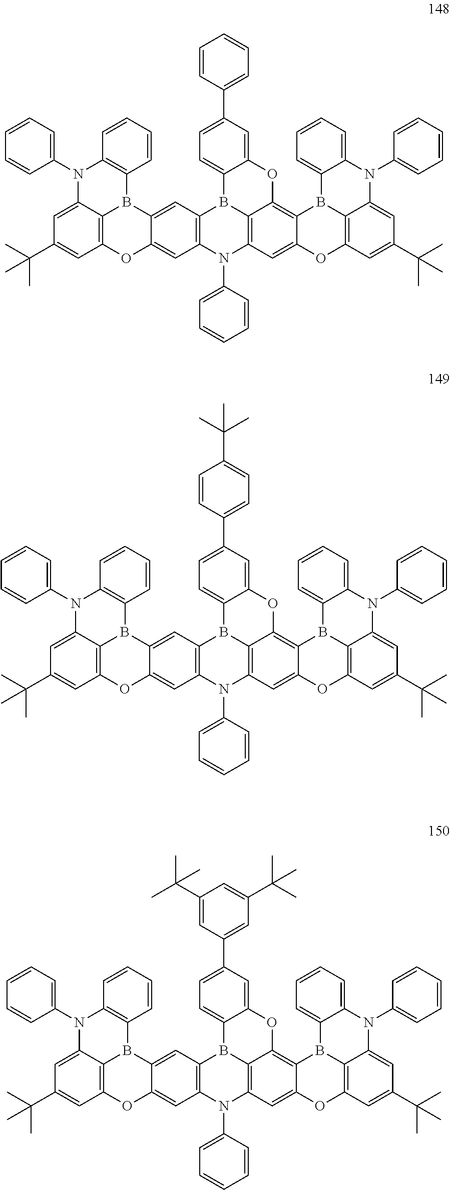 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)O2 ; CC(C)(C)c1ccc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1] 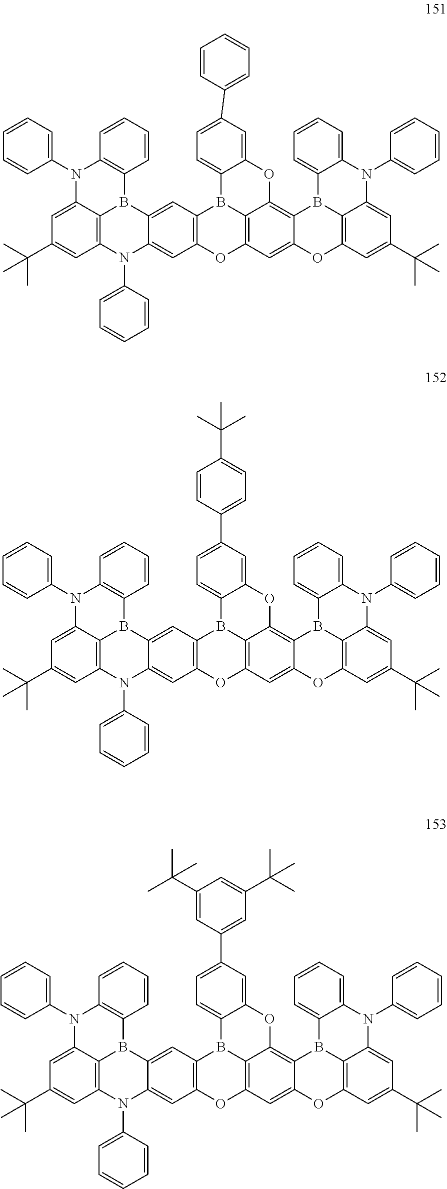 [SMILES: CC(C)(C)c1cc2c3c(c1)N(c1ccccc1)c1ccccc1B3c1c(cc3c4c1Oc1cc(-c5ccccc5)ccc1B4c1cc4c(cc1O3)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc(C(C)(C)C)c1] 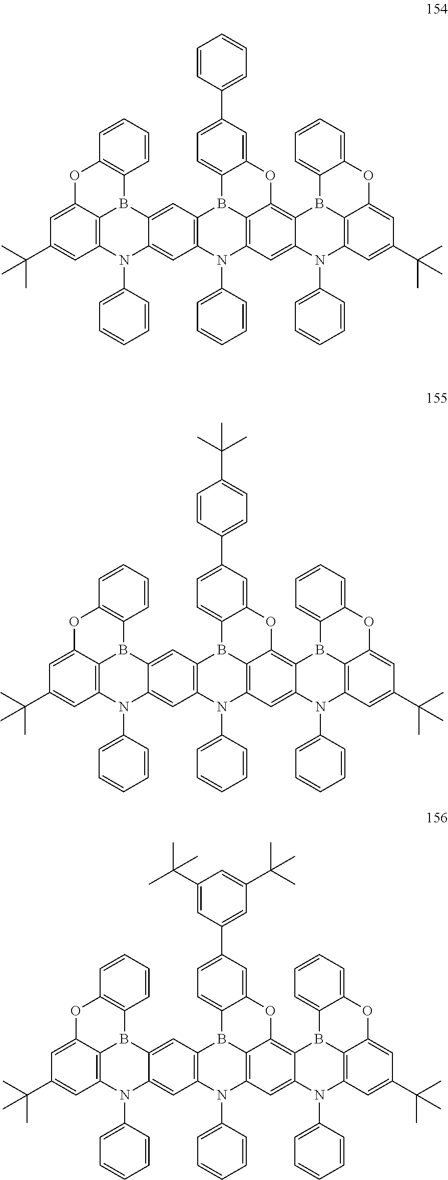 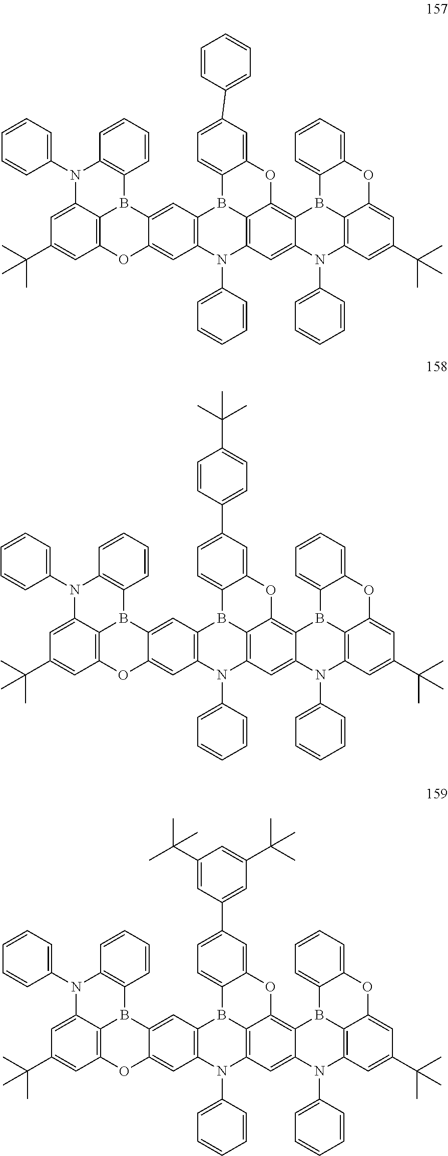 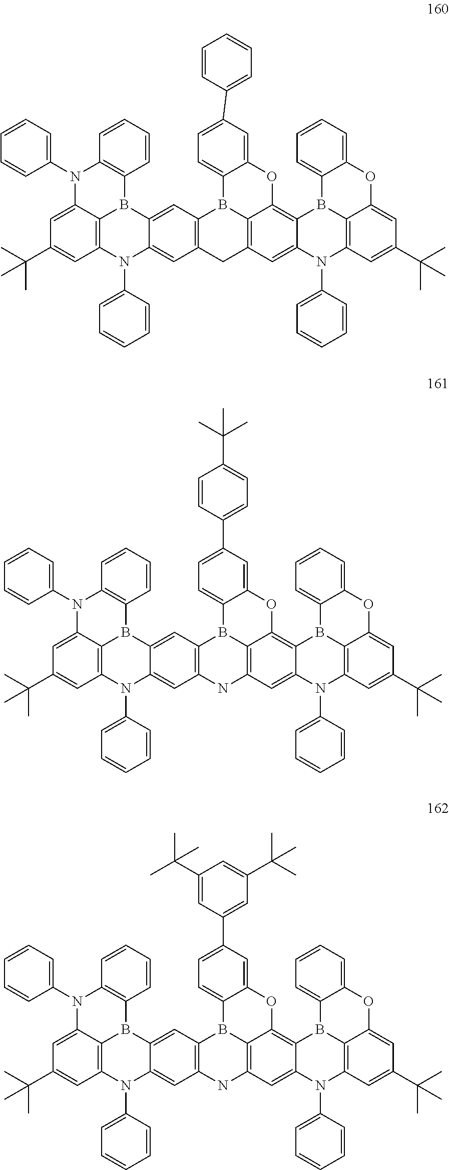 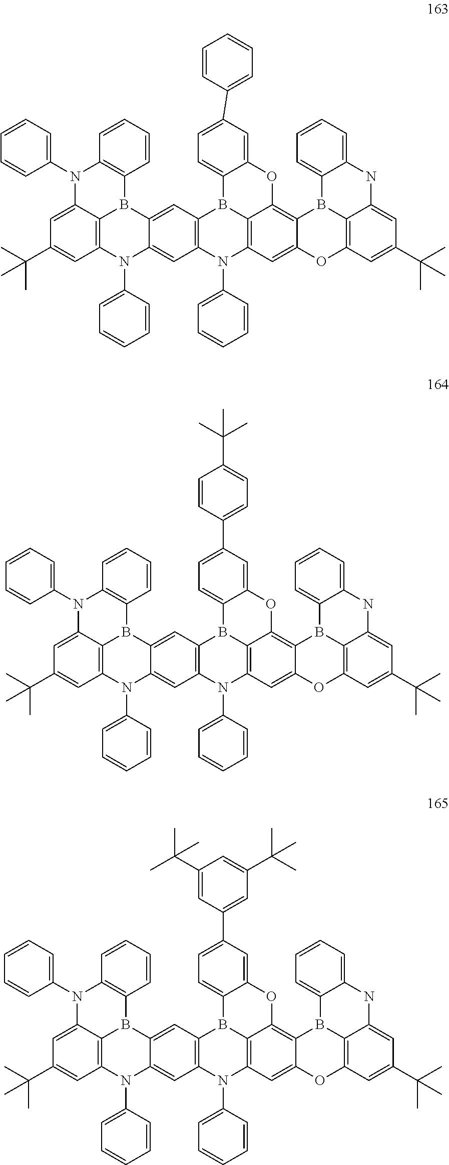 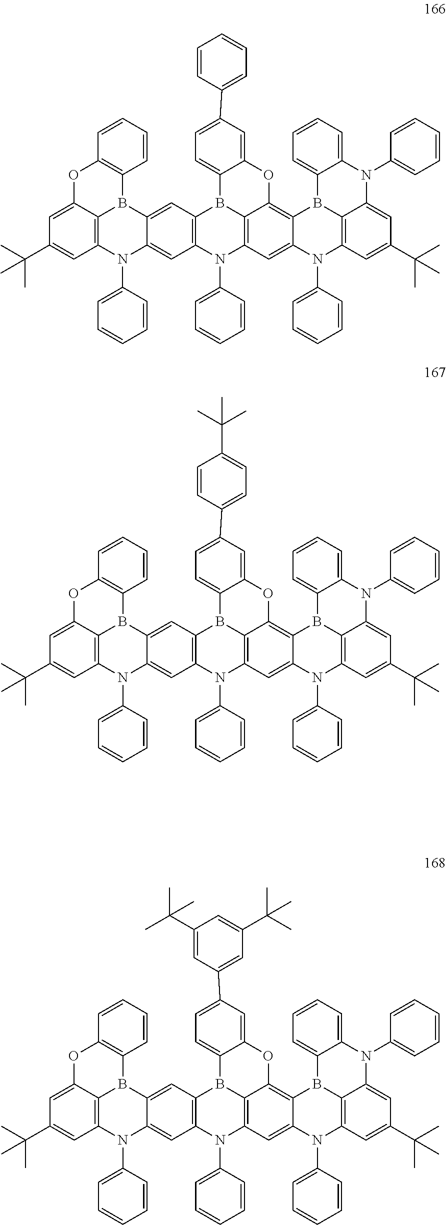 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc(C(C)(C)C)c1] 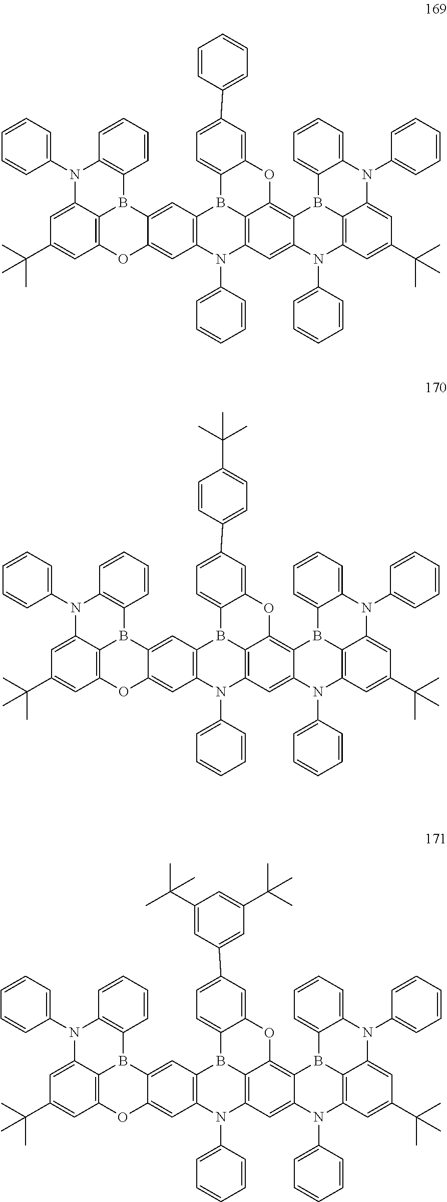 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)N2c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc(C(C)(C)C)c1] 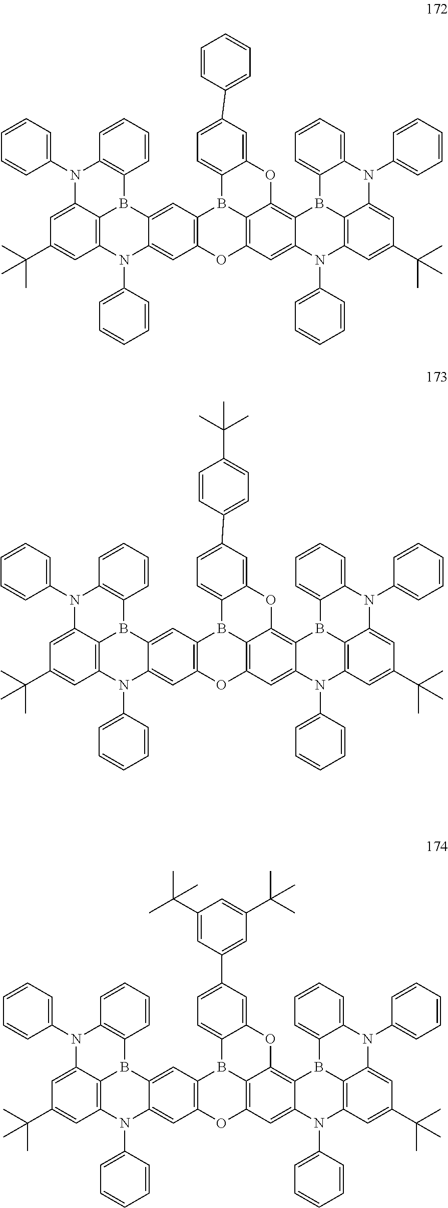 [SMILES: CC(C)(C)c1cc2c3c(c1)N(c1ccccc1)c1cc4c(cc1B3c1ccccc1N2c1ccccc1)B1c2ccc(-c3ccccc3)cc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc(C(C)(C)C)c1] 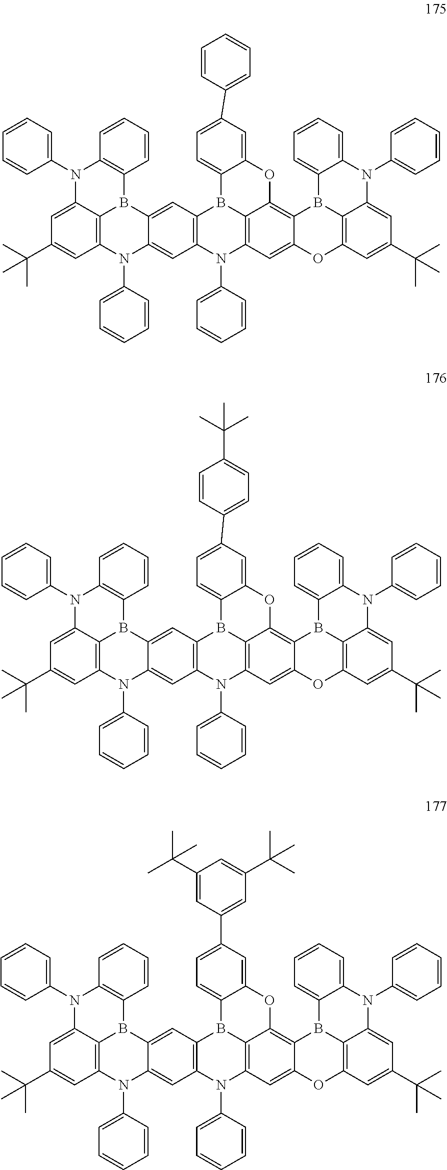 [SMILES: CC(C)(C)c1cc2c3c(c1)N(c1ccccc1)c1ccccc1B3c1c(cc3c4c1Oc1cc(-c5ccccc5)ccc1B4c1cc4c(cc1N3c1ccccc1)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1] 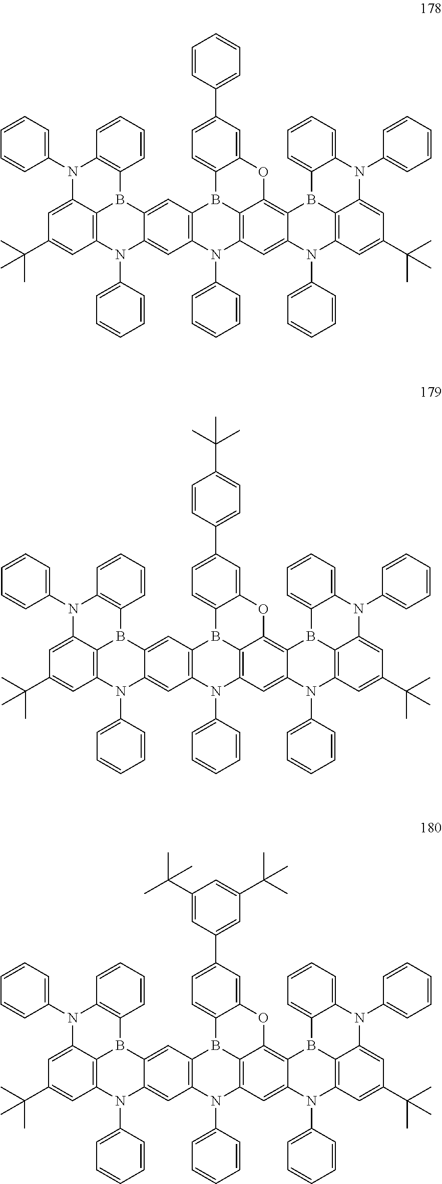 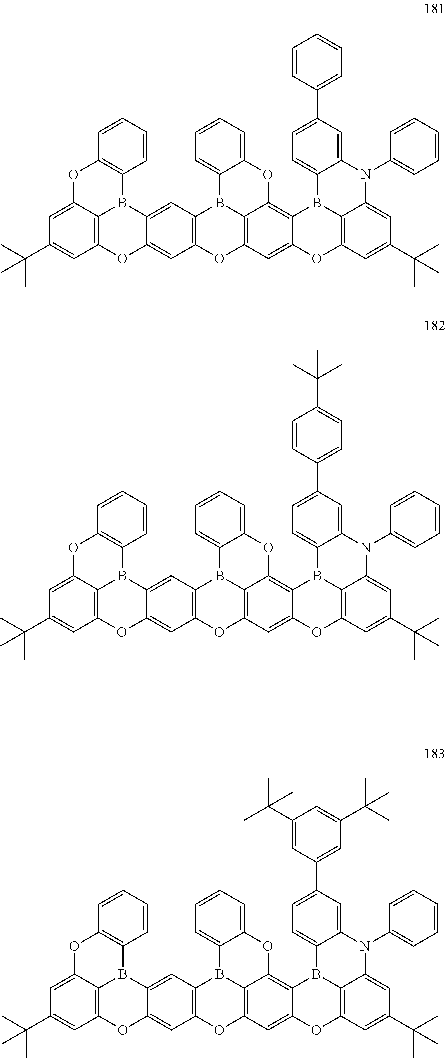 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc(C(C)(C)C)c1] 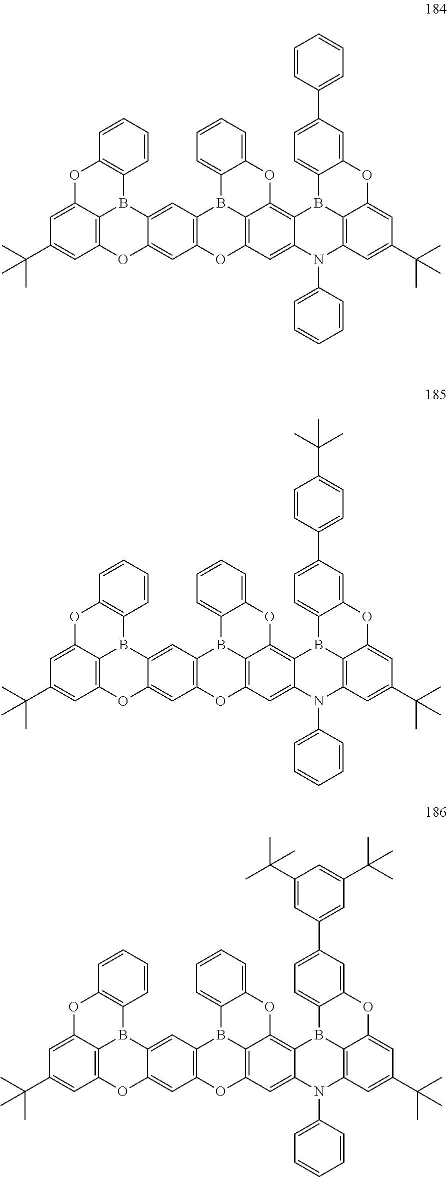 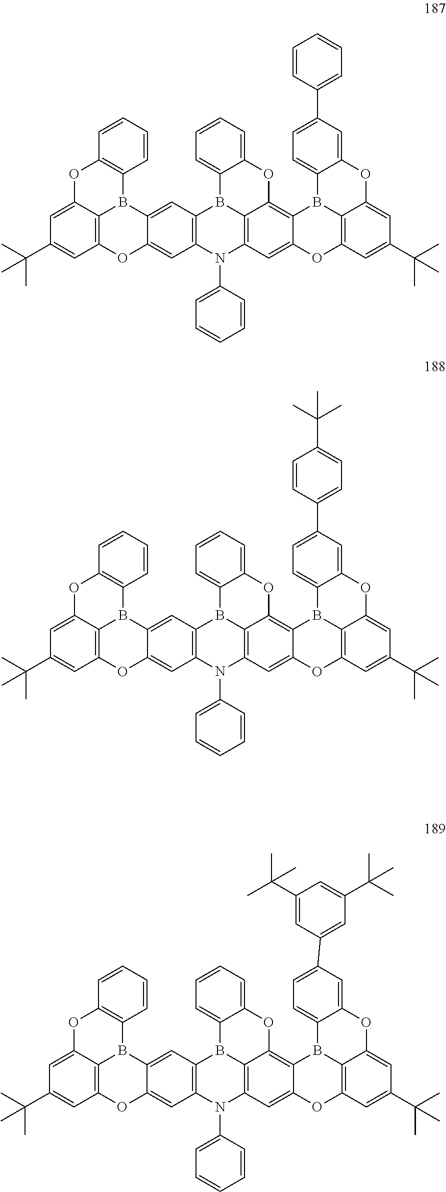 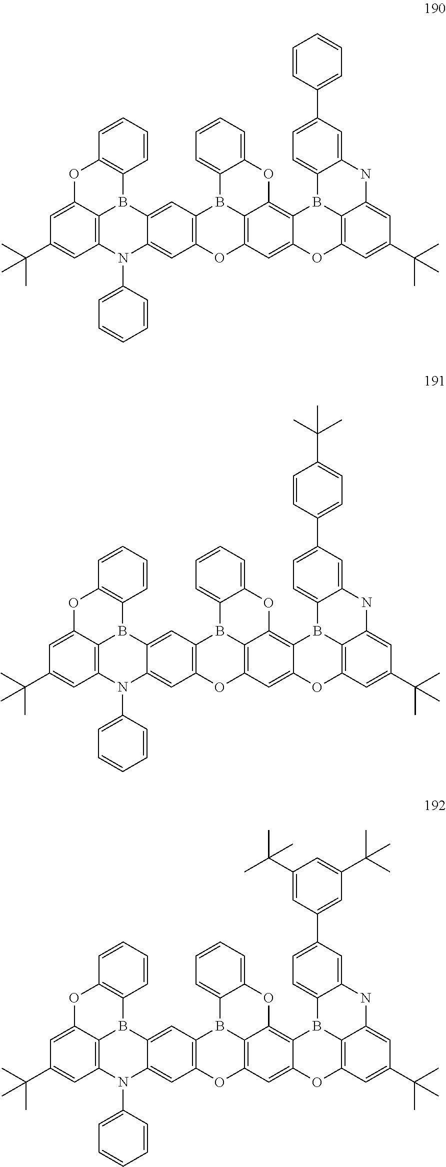 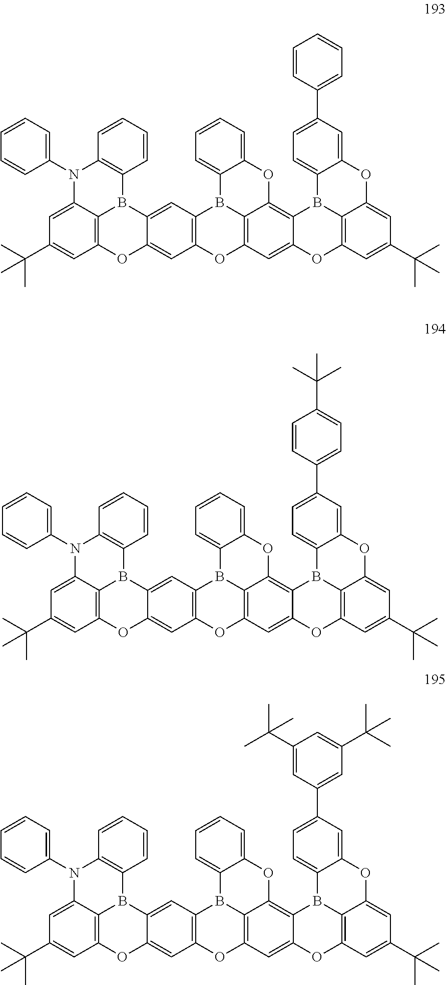 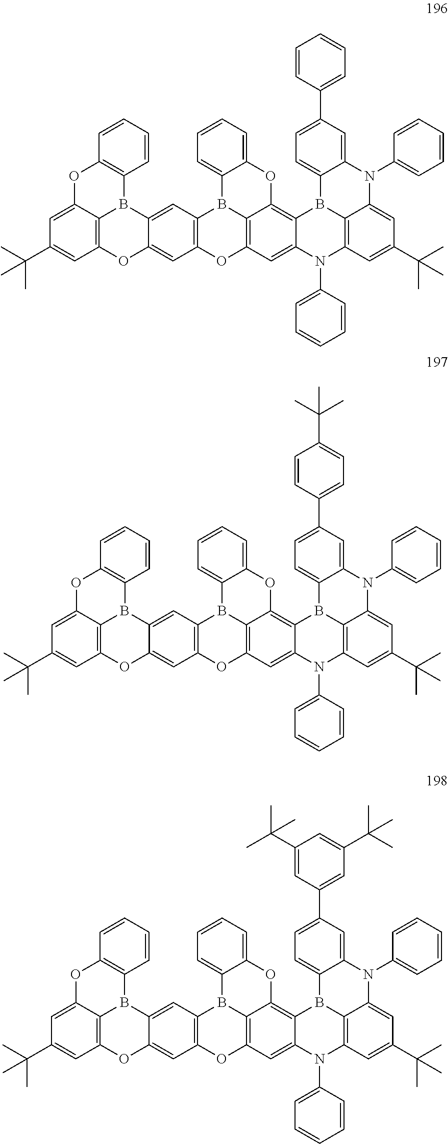 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)N1c1ccccc1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc(C(C)(C)C)c1] 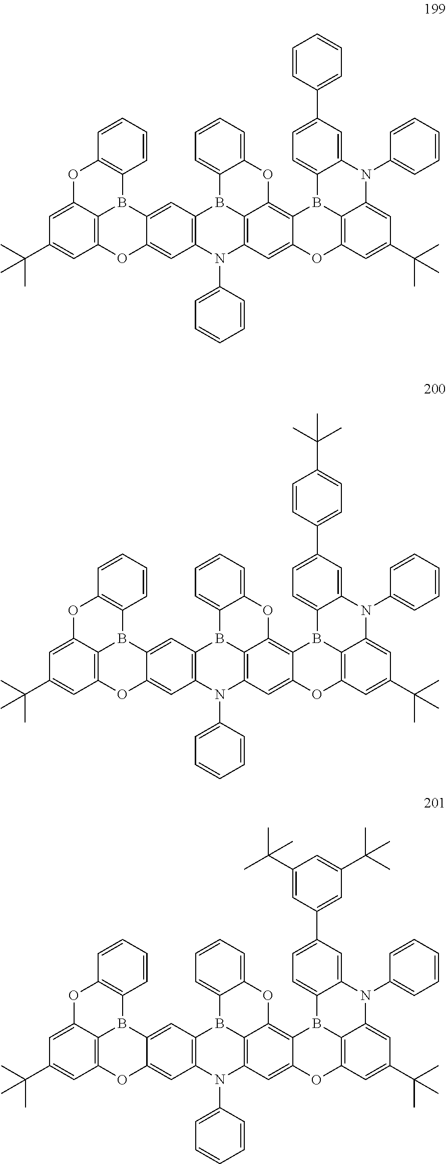 [SMILES: CC(C)(C)c1cc2c3c(c1)Oc1cc4c(cc1B3c1ccccc1O2)B1c2ccccc2Oc2c3c(cc(c21)N4c1ccccc1)Oc1cc(C(C)(C)C)cc2c1B3c1ccc(-c3ccccc3)cc1N2c1ccccc1 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc(C(C)(C)C)c1] 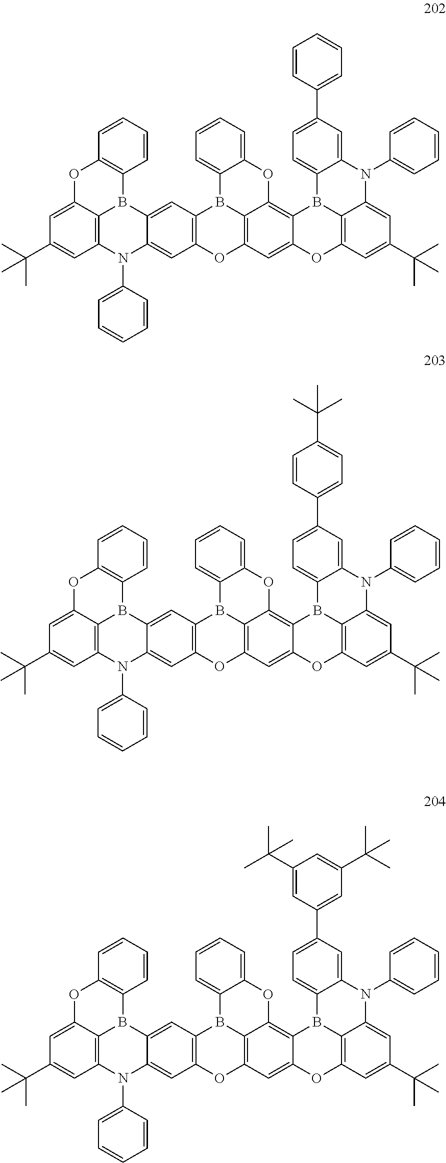 [SMILES: CC(C)(C)c1cc2c3c(c1)N(c1ccccc1)c1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc(C(C)(C)C)c1] 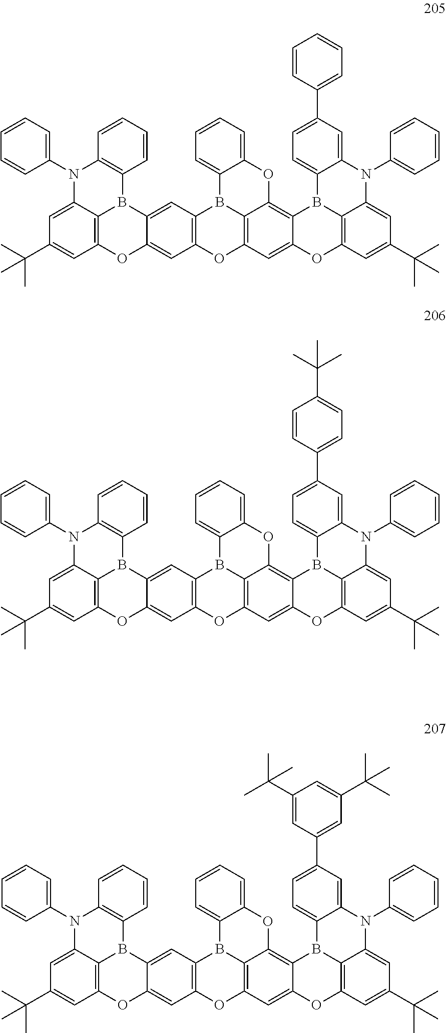 [SMILES: CC(C)(C)c1cc2c3c(c1)N(c1ccccc1)c1ccccc1B3c1cc3c(cc1O2)Oc1cc2c(c4c1B3c1ccccc1O4)B1c3ccc(-c4ccccc4)cc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc(C(C)(C)C)c1] 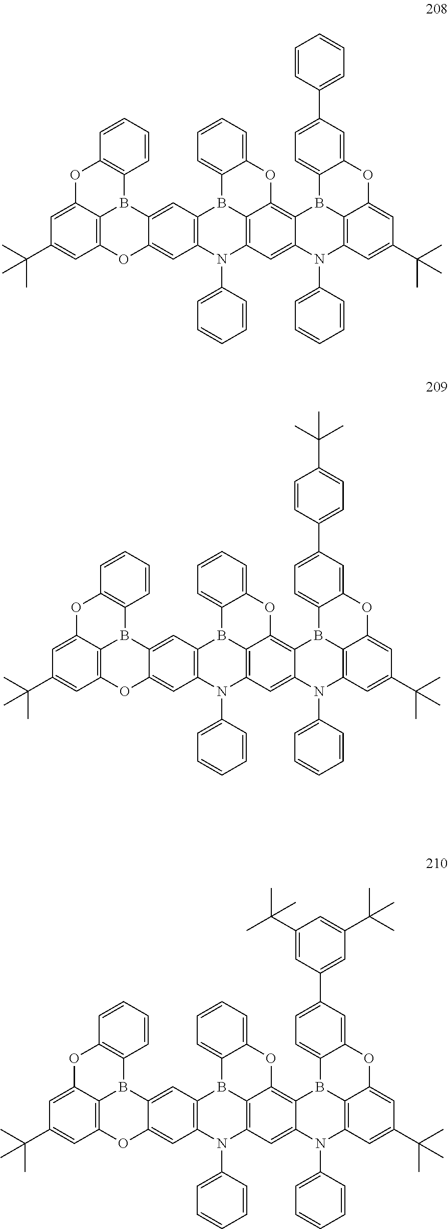 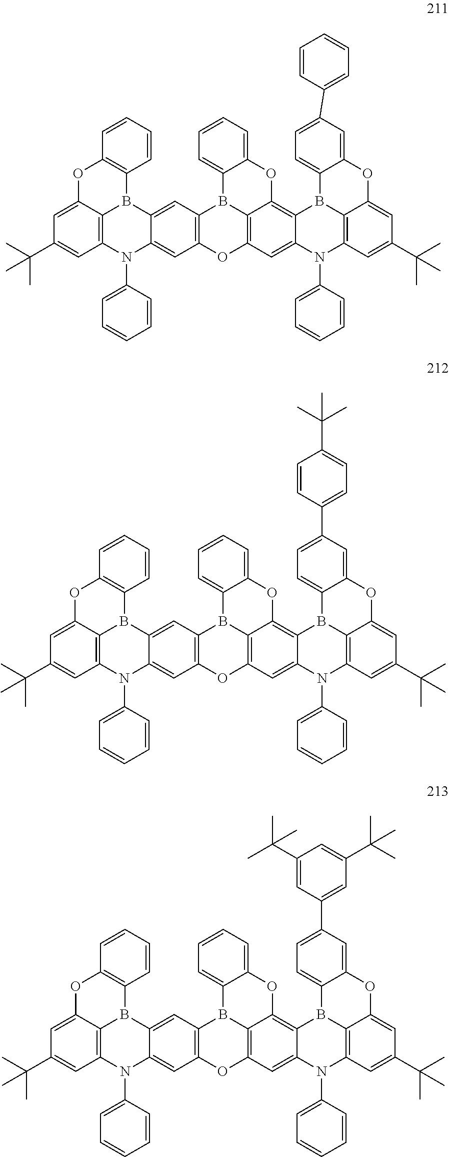 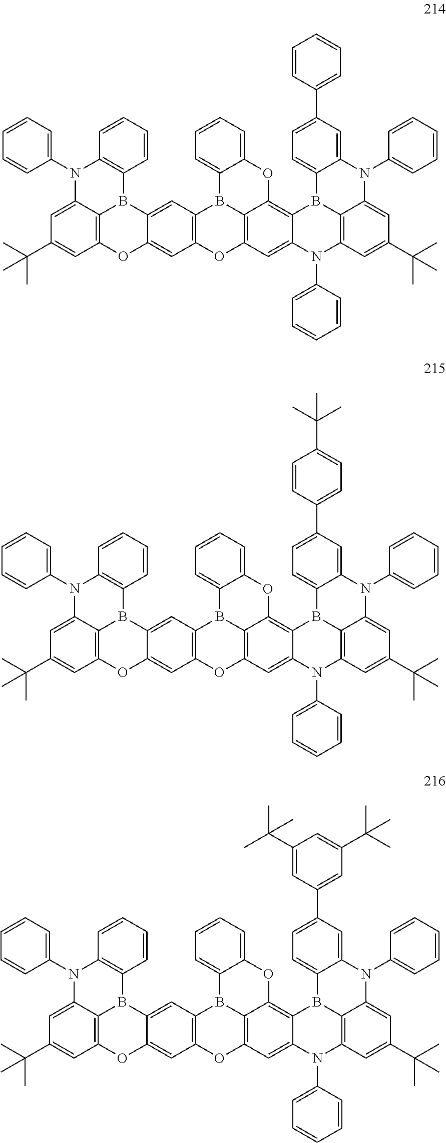 [SMILES: CC(C)(C)c1cc2c3c(c1)N(c1ccccc1)c1ccccc1B3c1cc3c(cc1O2)Oc1cc2c(c4c1B3c1ccccc1O4)B1c3ccc(-c4ccccc4)cc3N(c3ccccc3)c3cc(C(C)(C)C)cc(c31)N2c1ccccc1 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)N4c2ccccc2)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)N4c2ccccc2)cc(C(C)(C)C)c1] 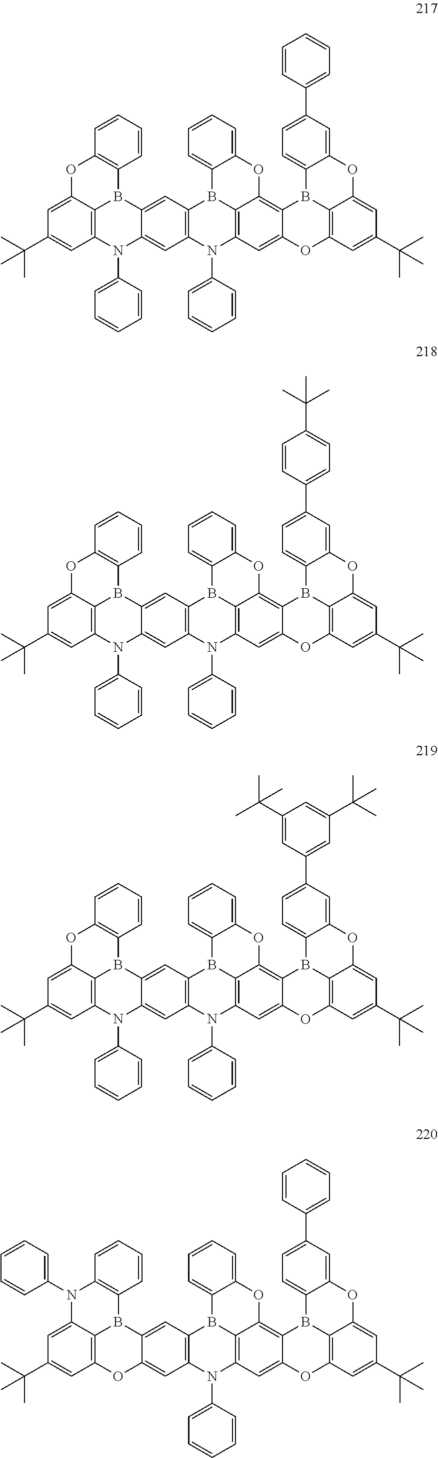 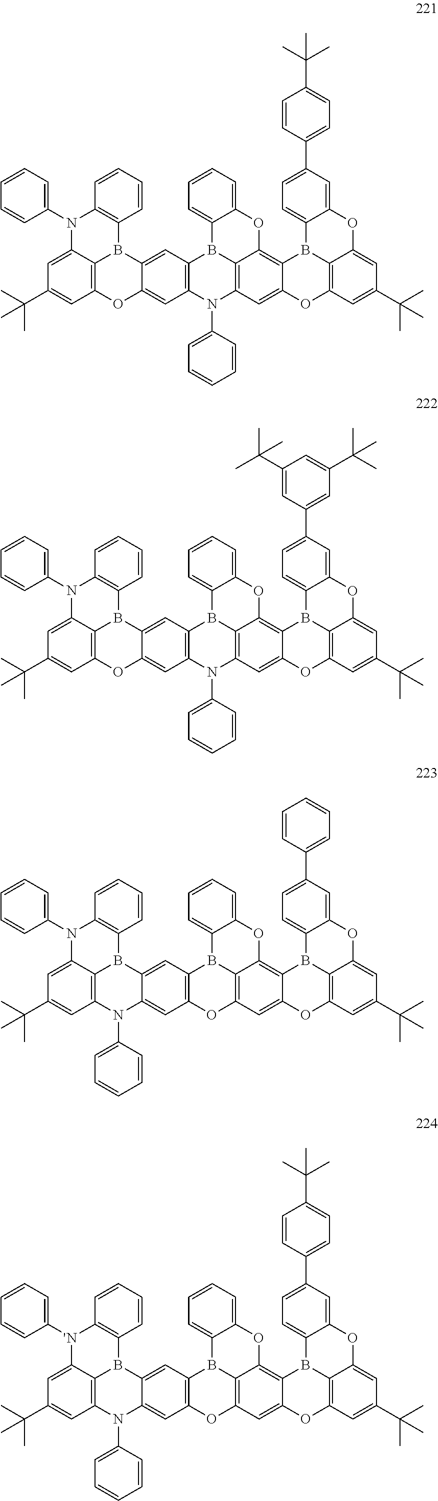 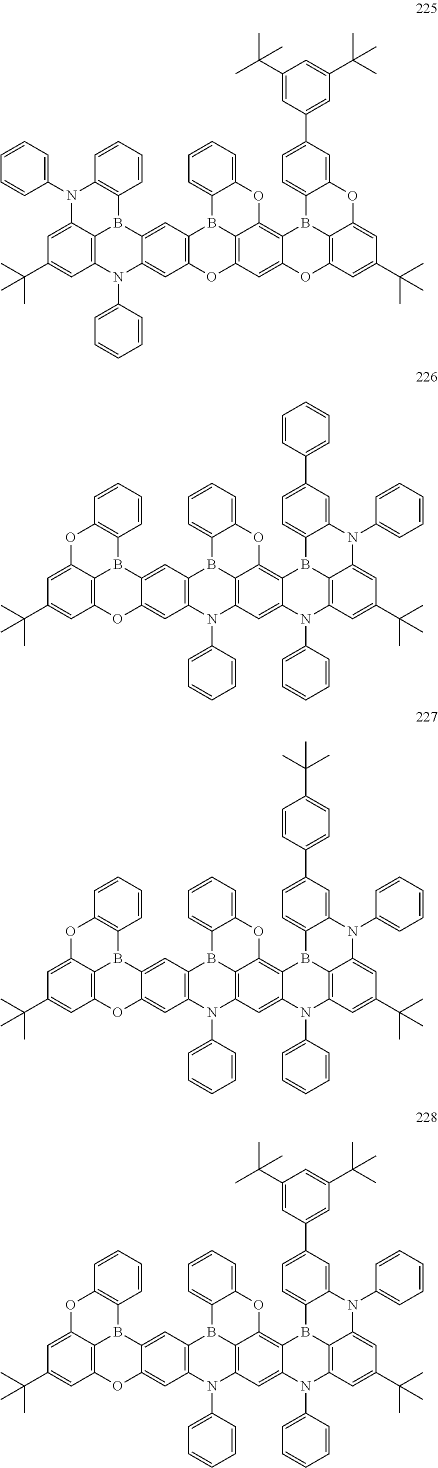 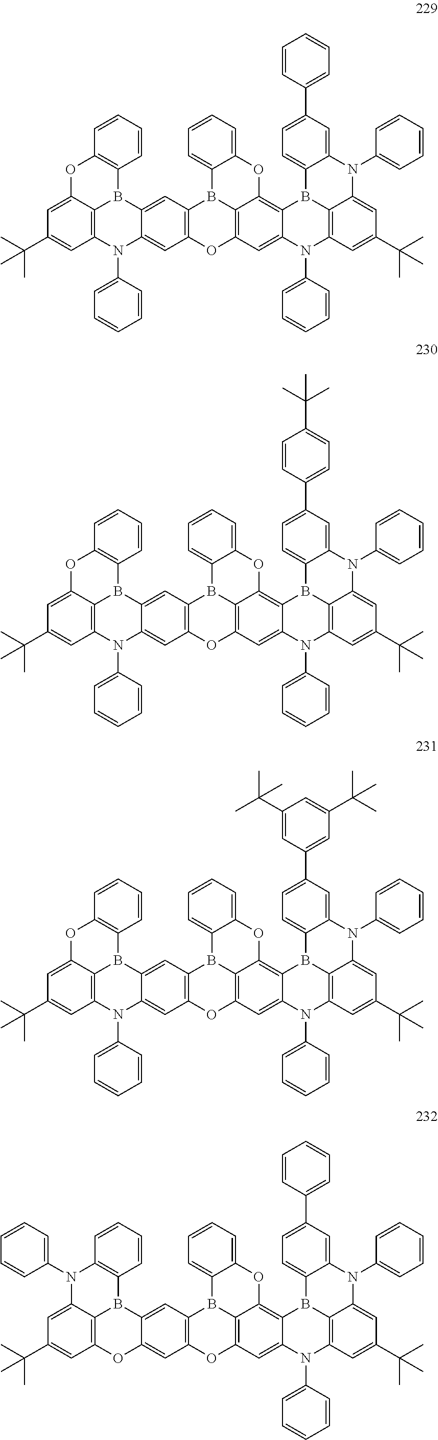 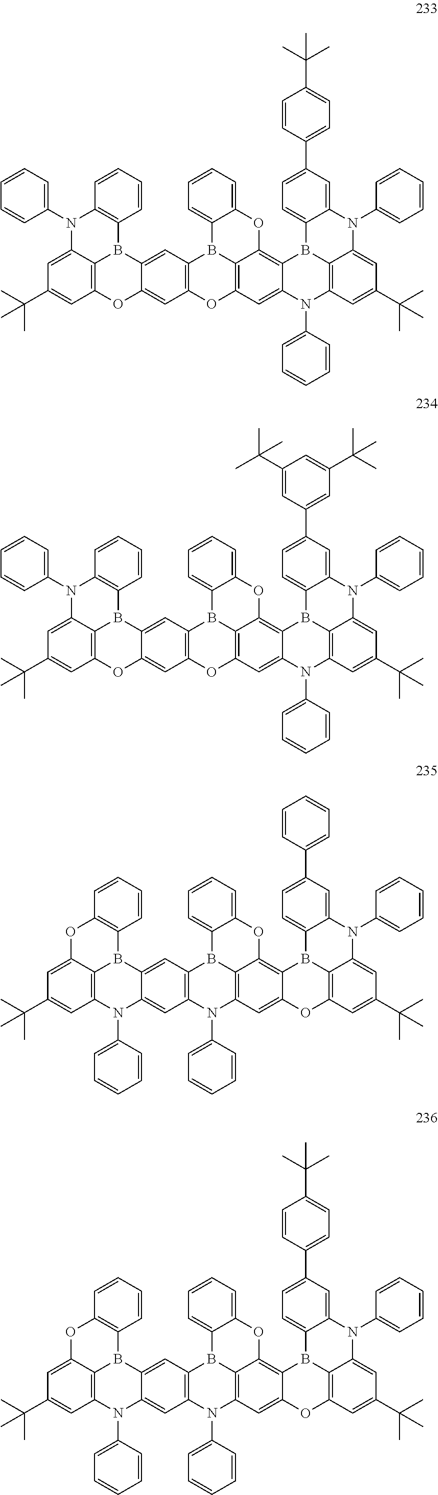 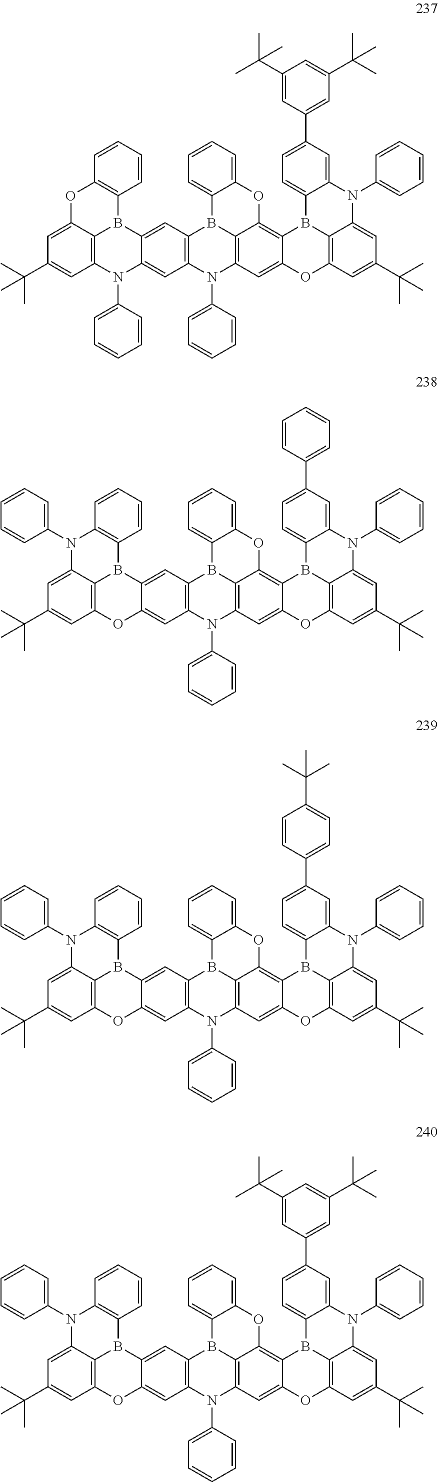 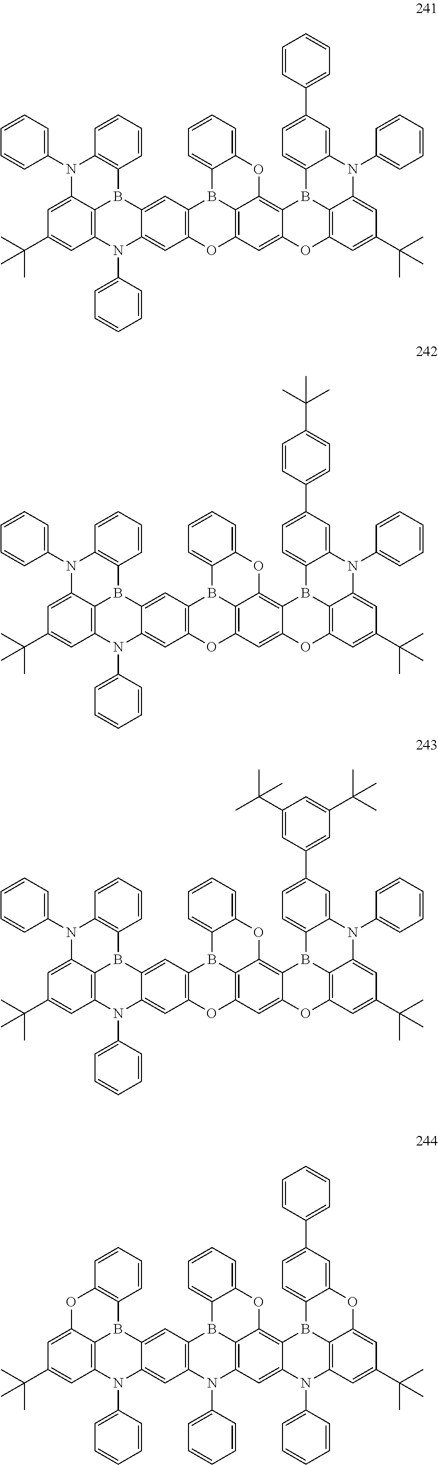 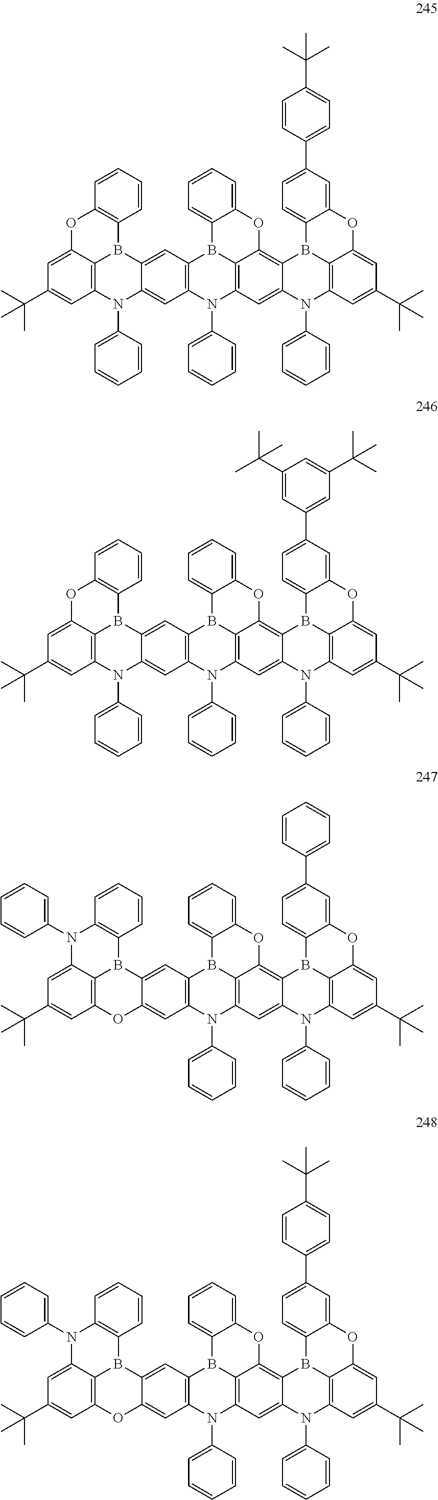 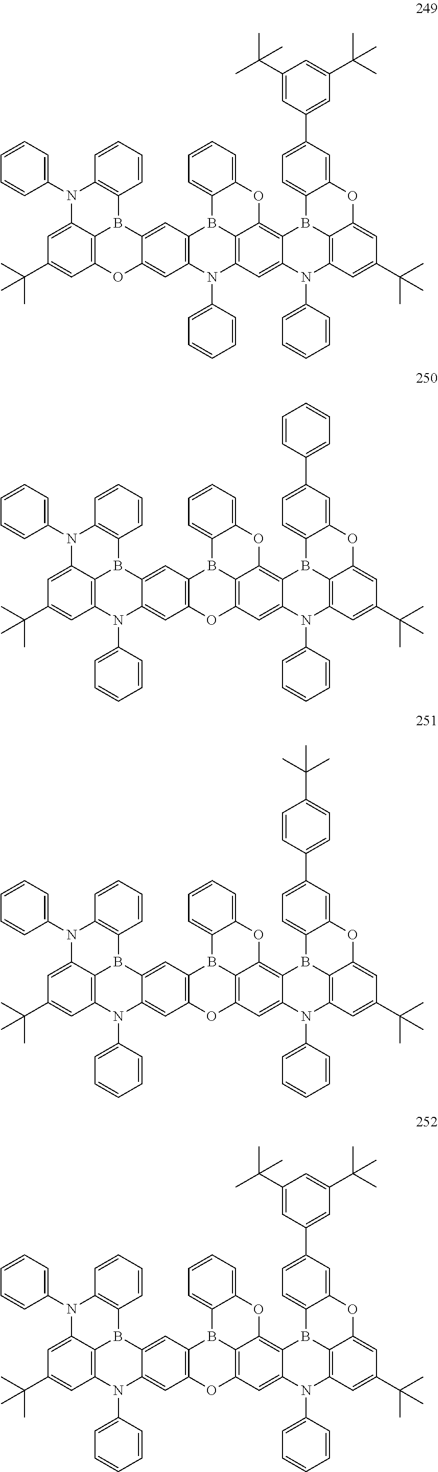 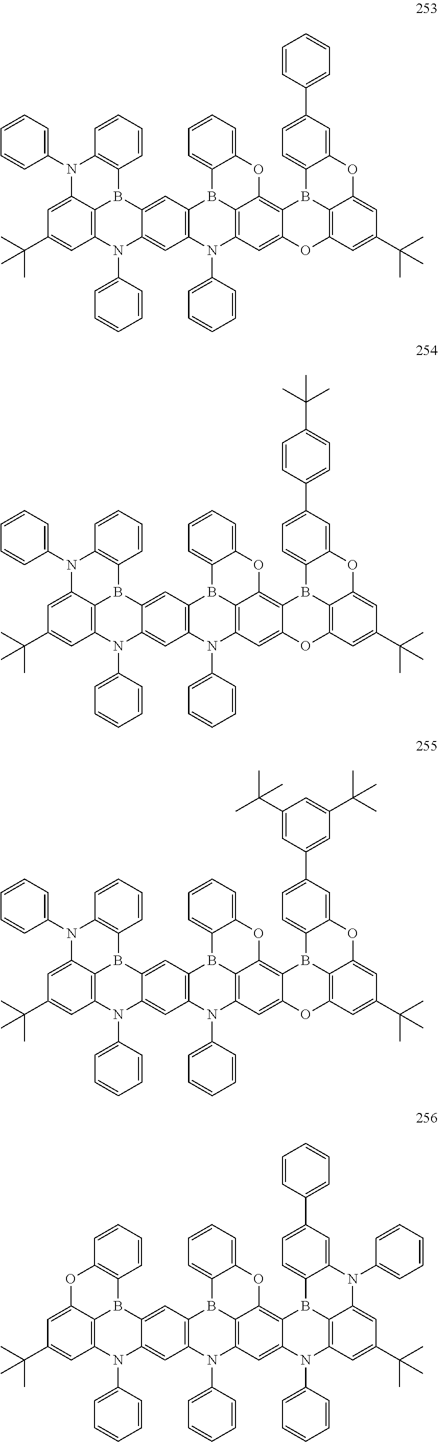 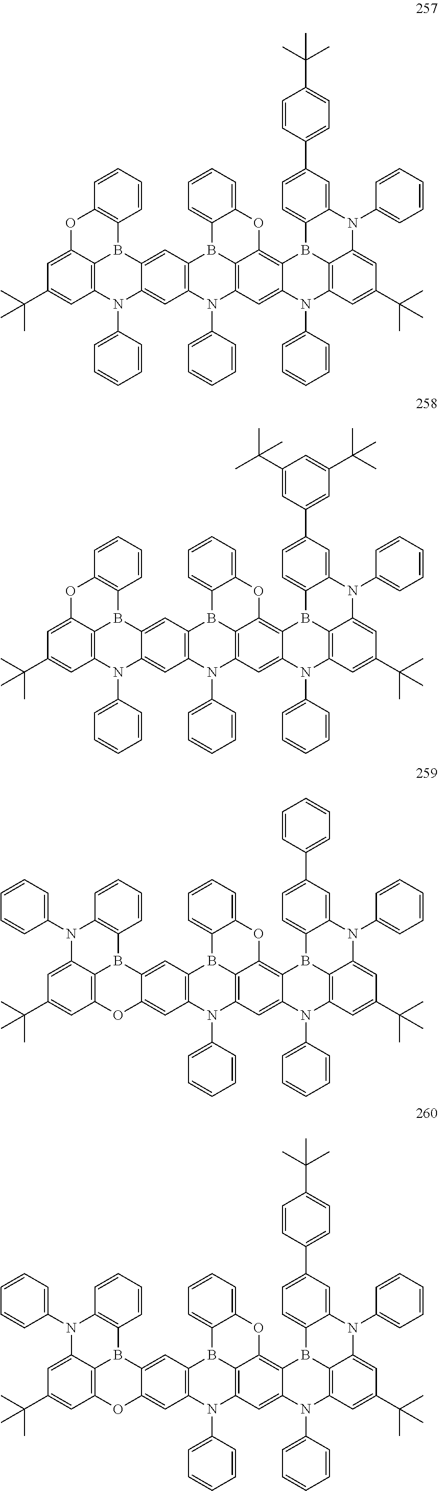 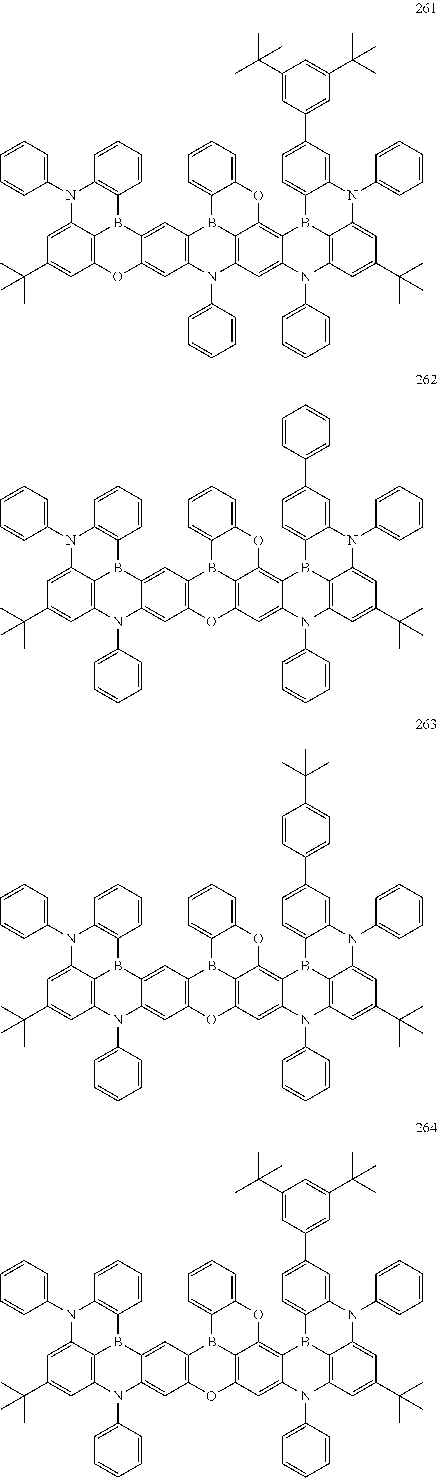 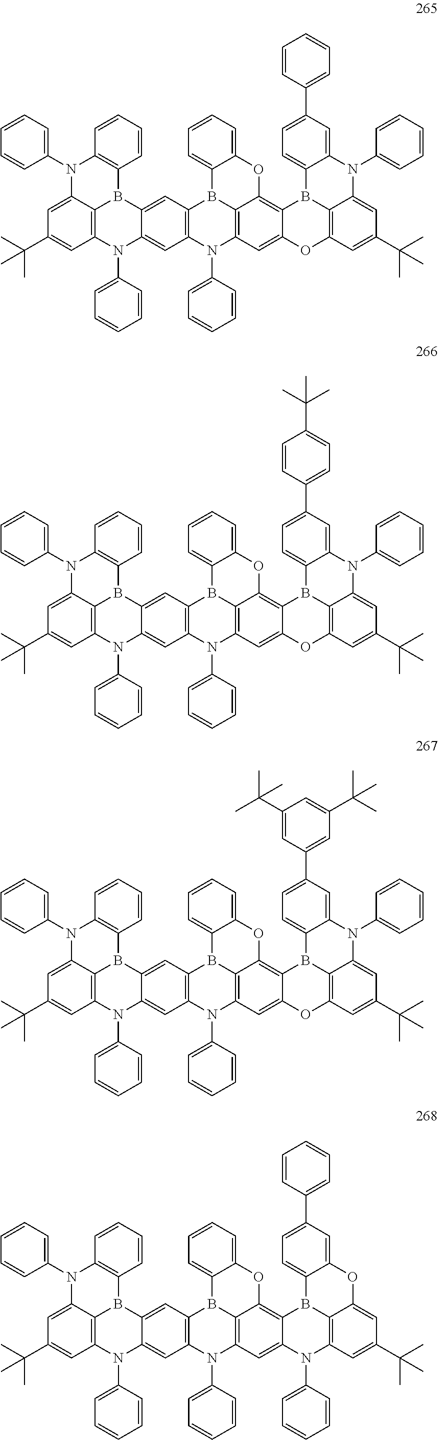 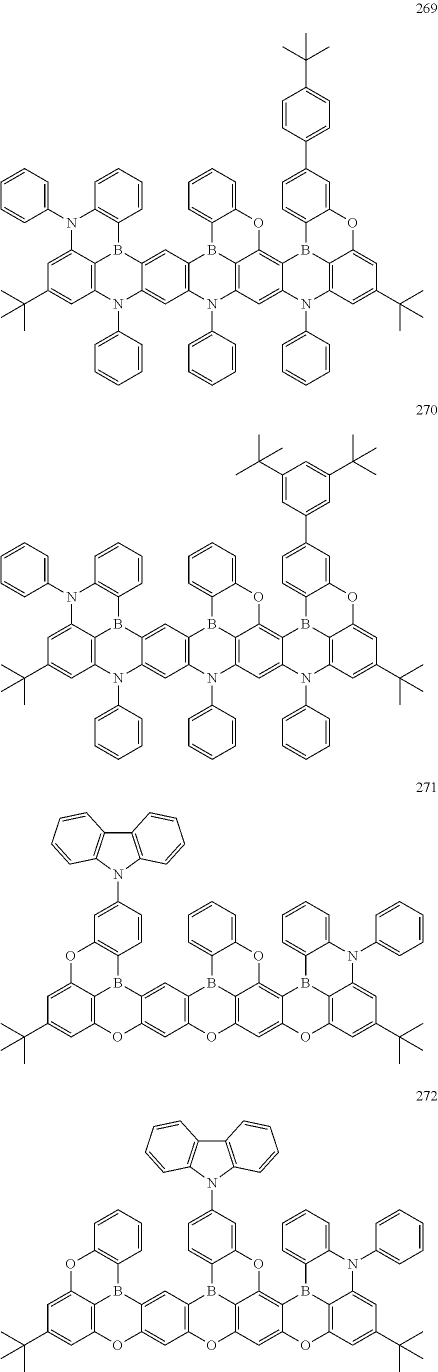 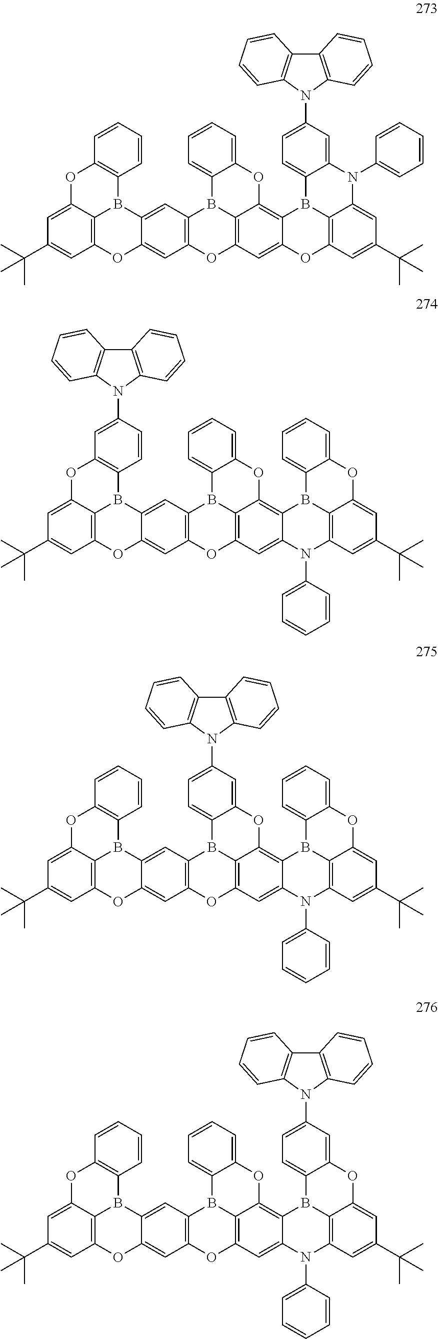 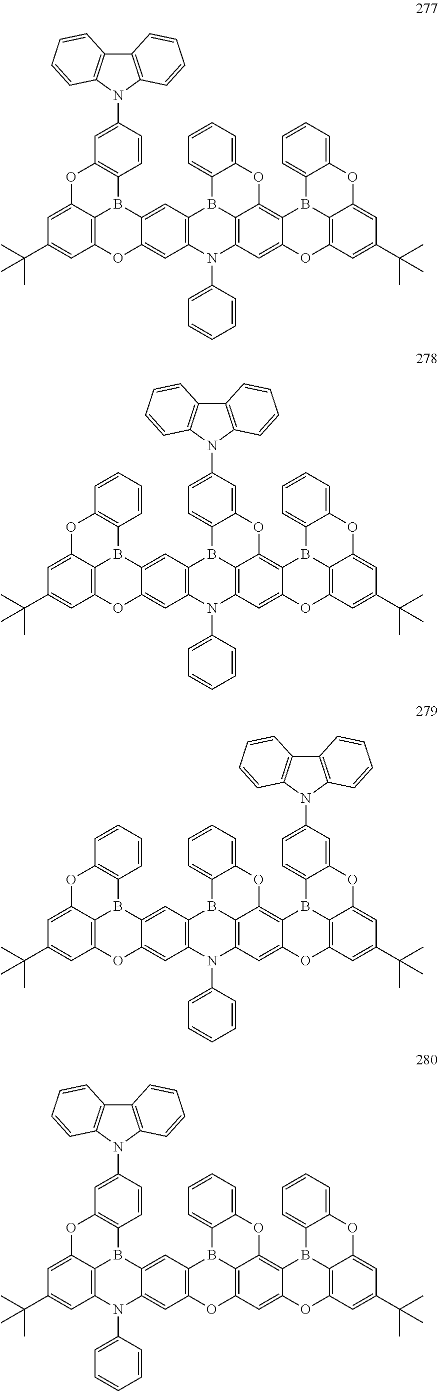 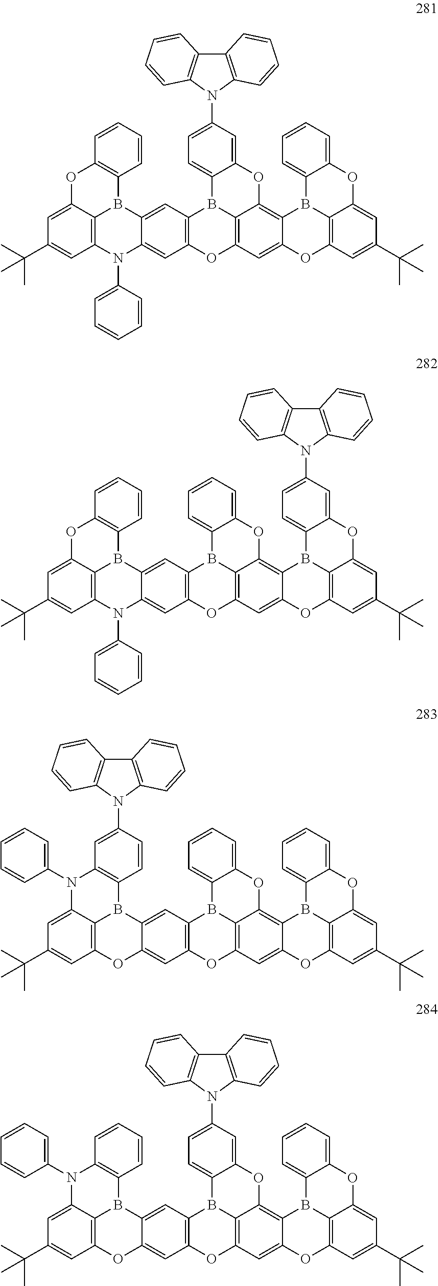 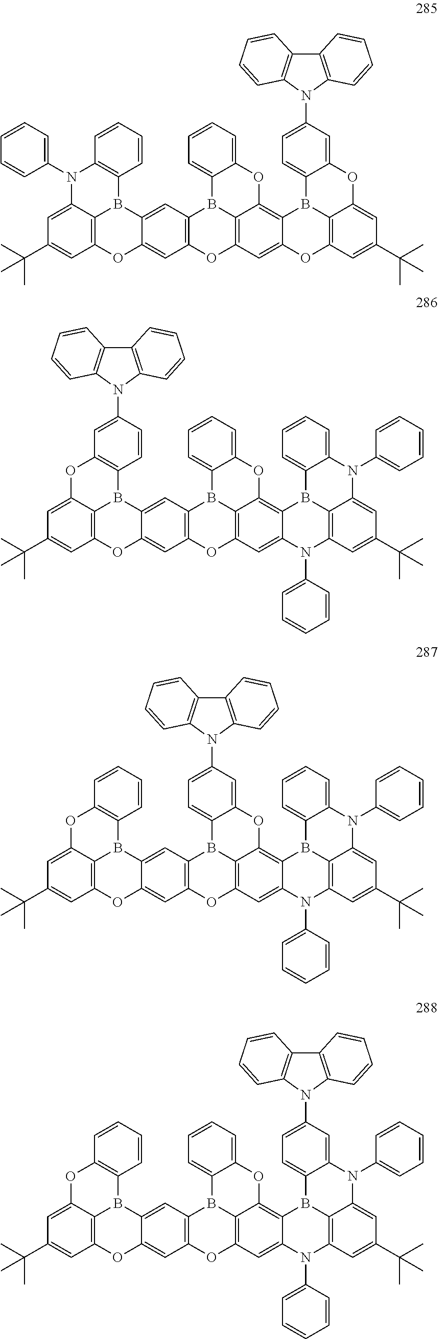 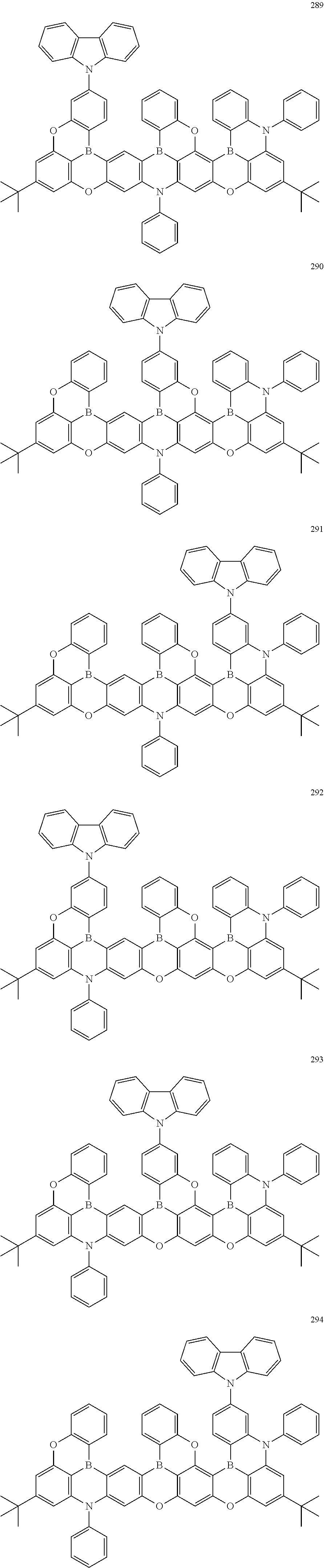 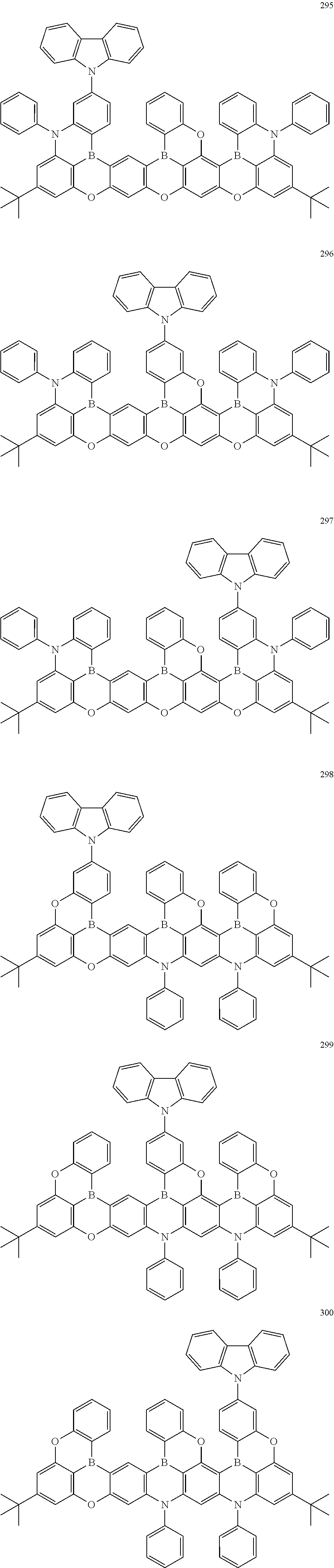 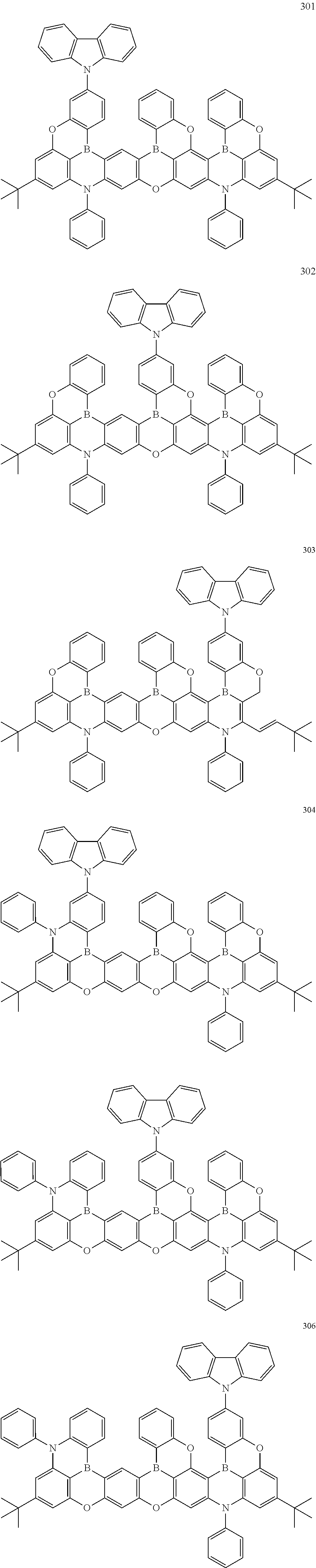 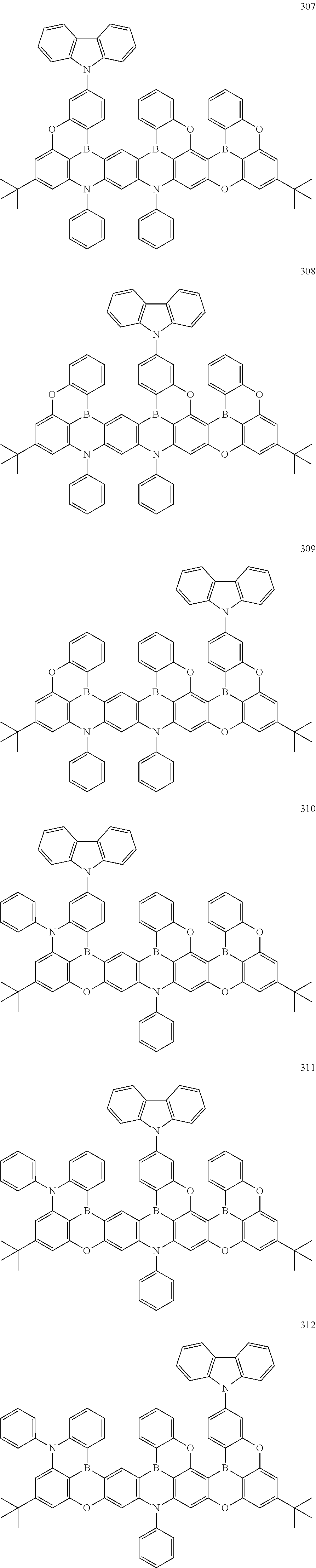 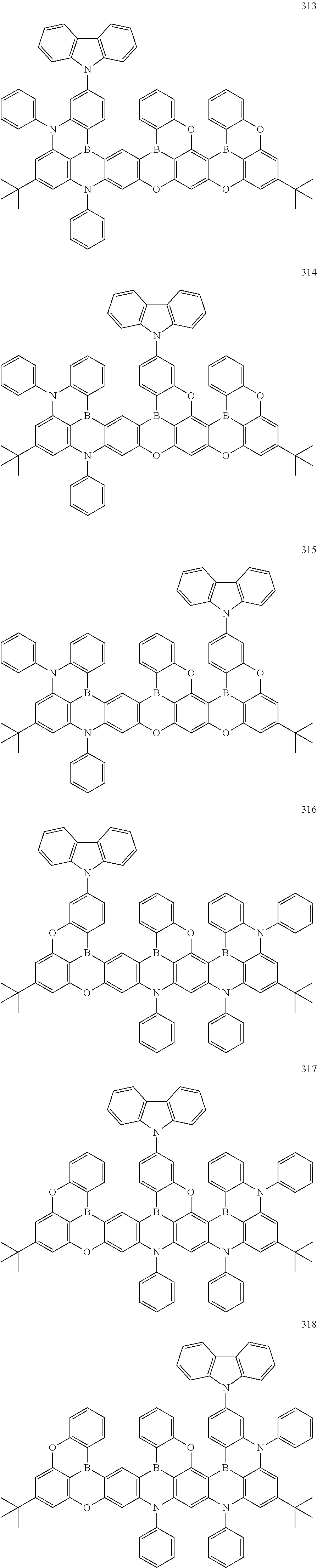 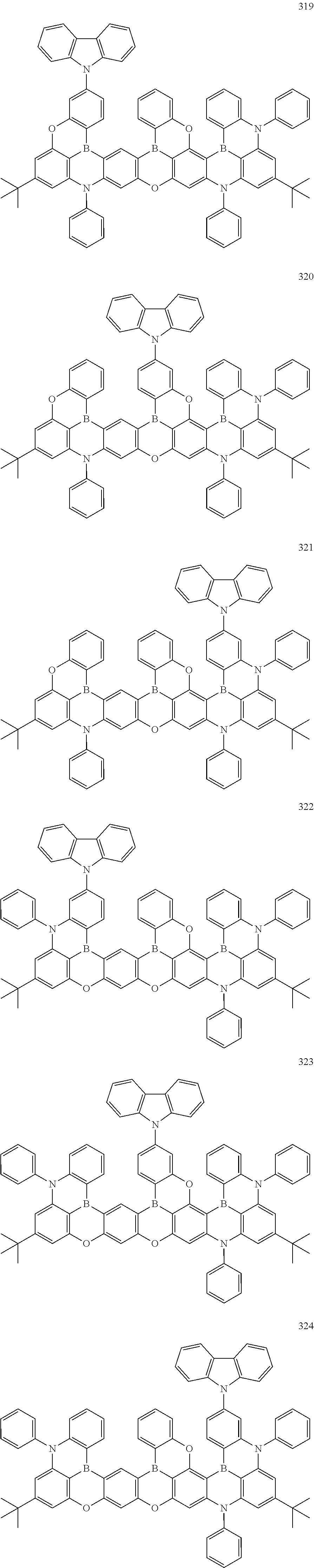 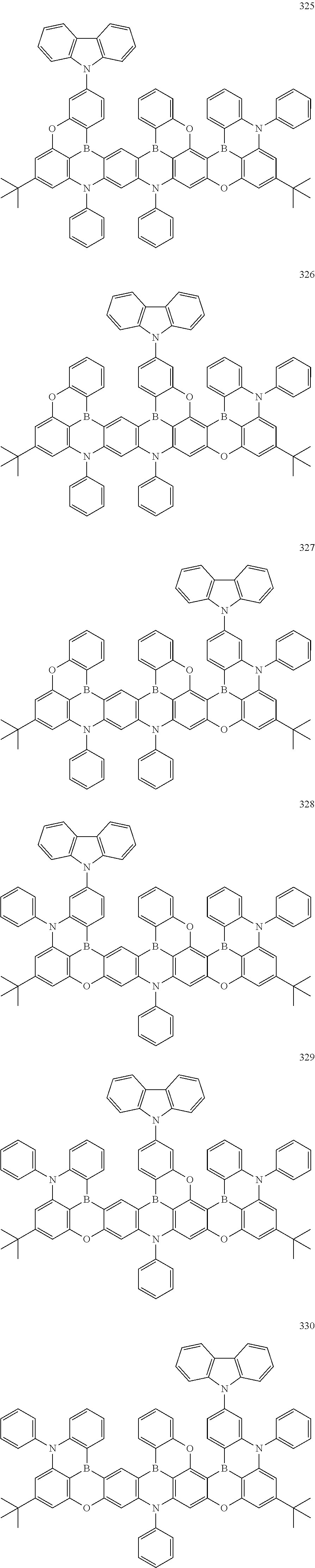 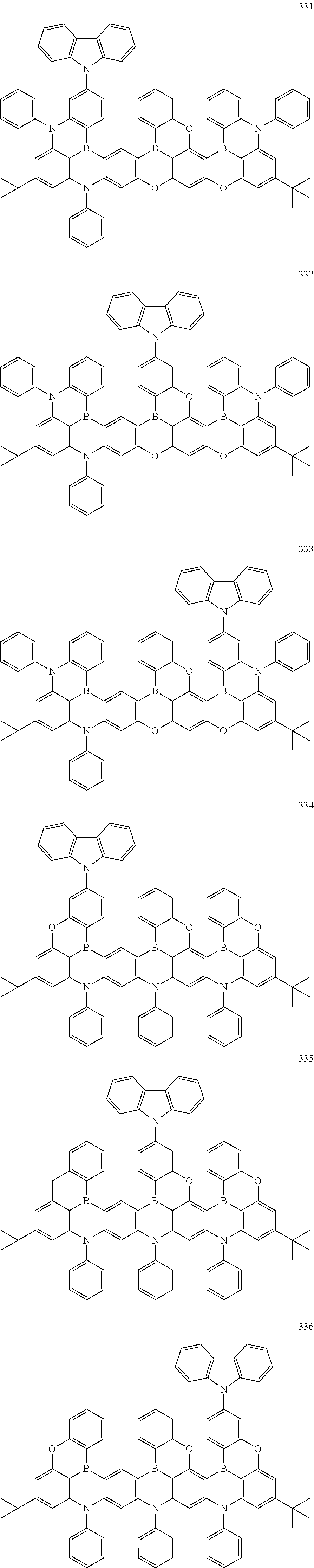 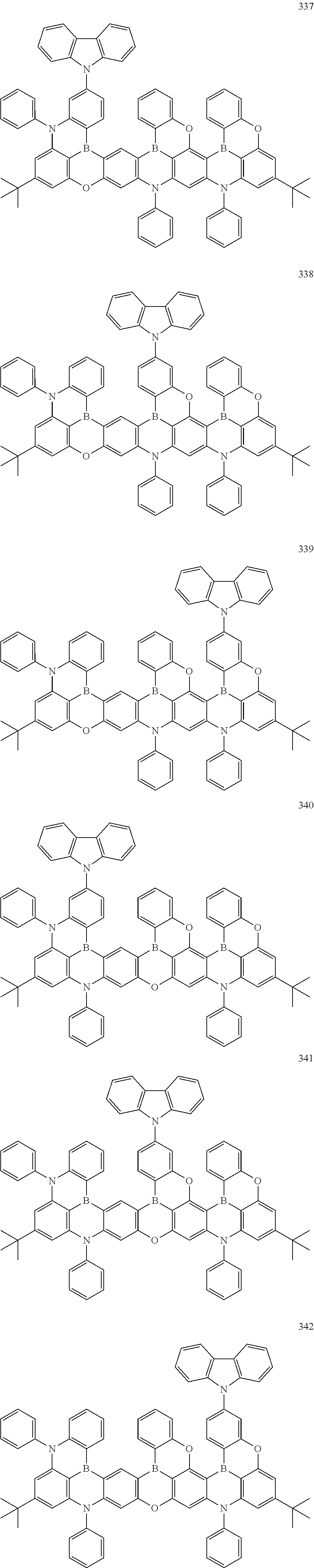 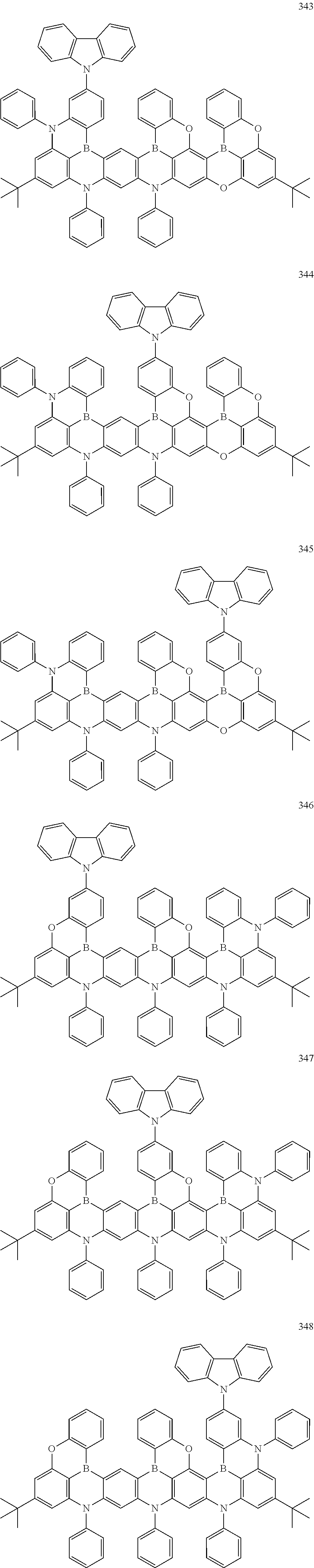 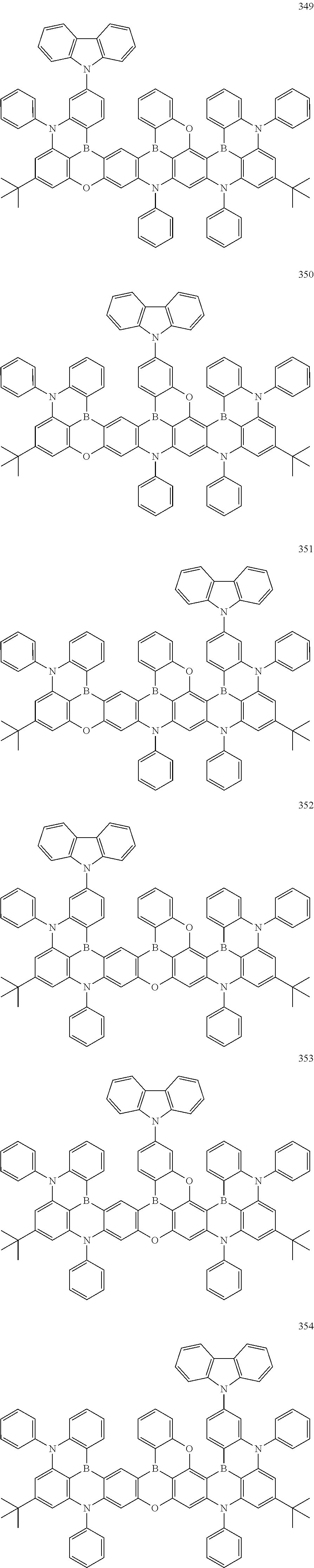 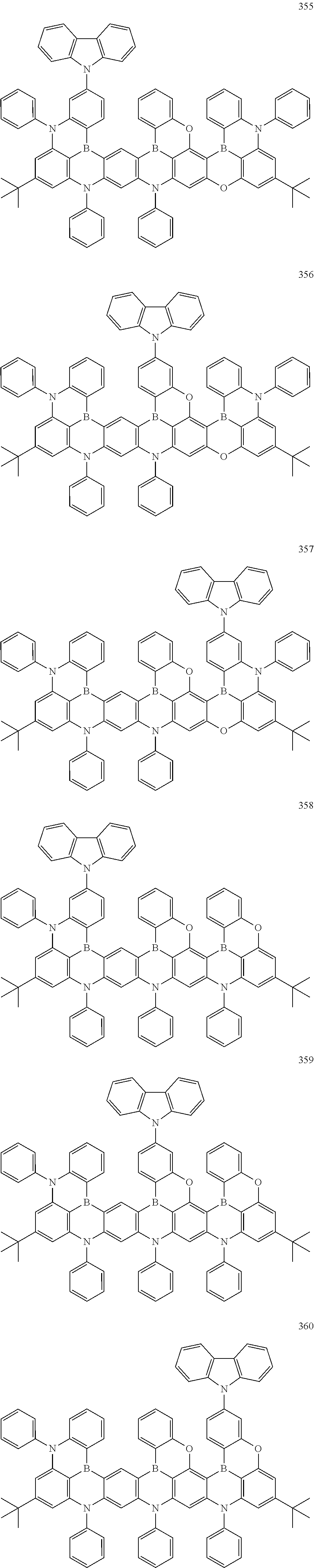 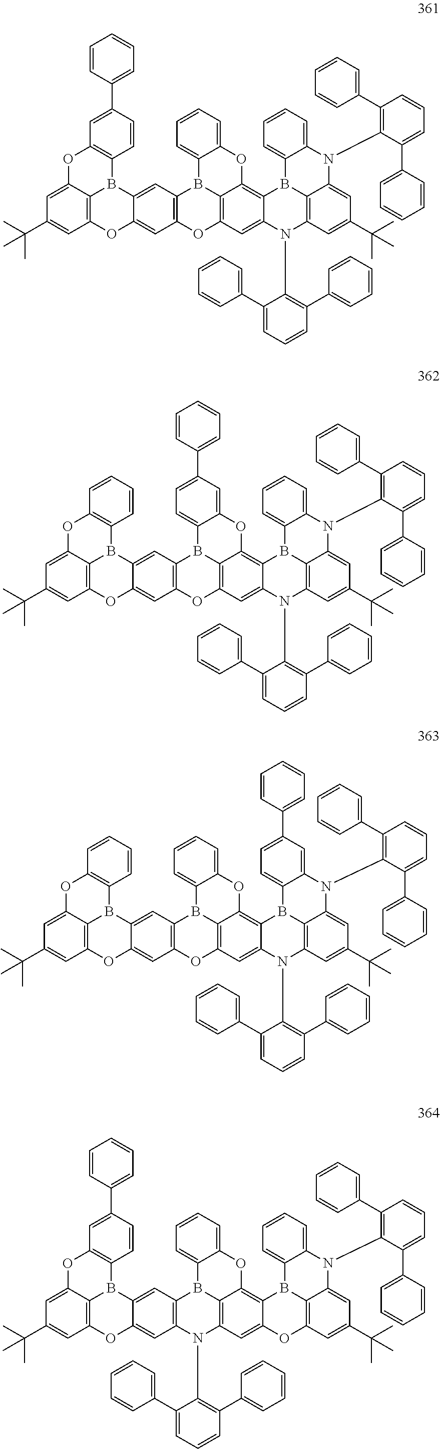 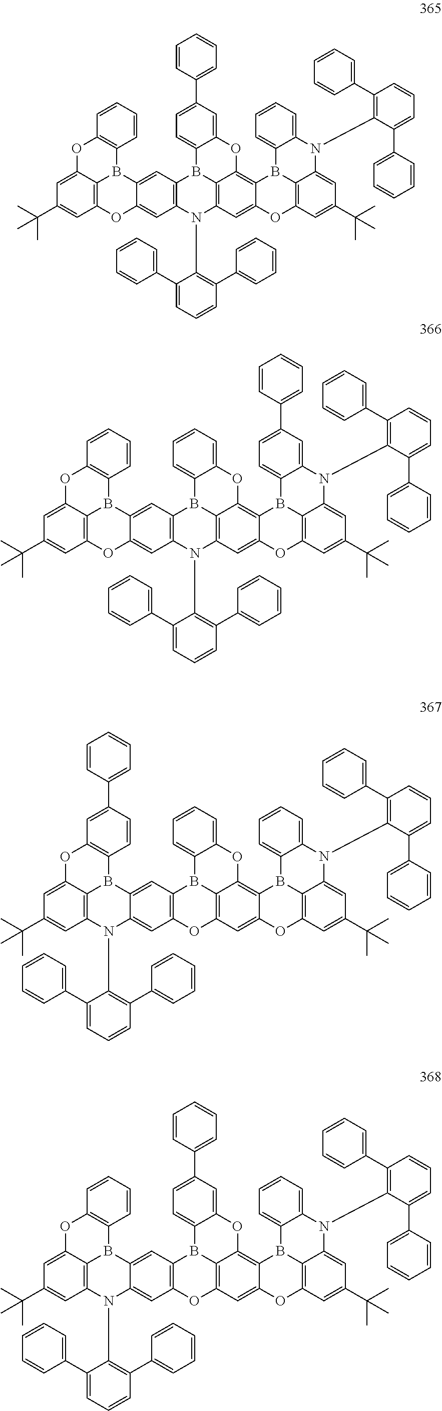 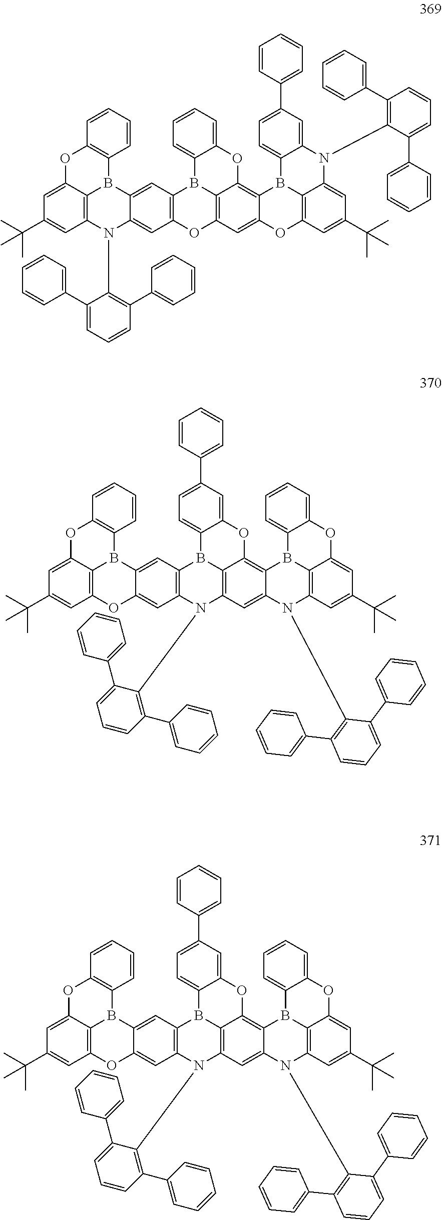 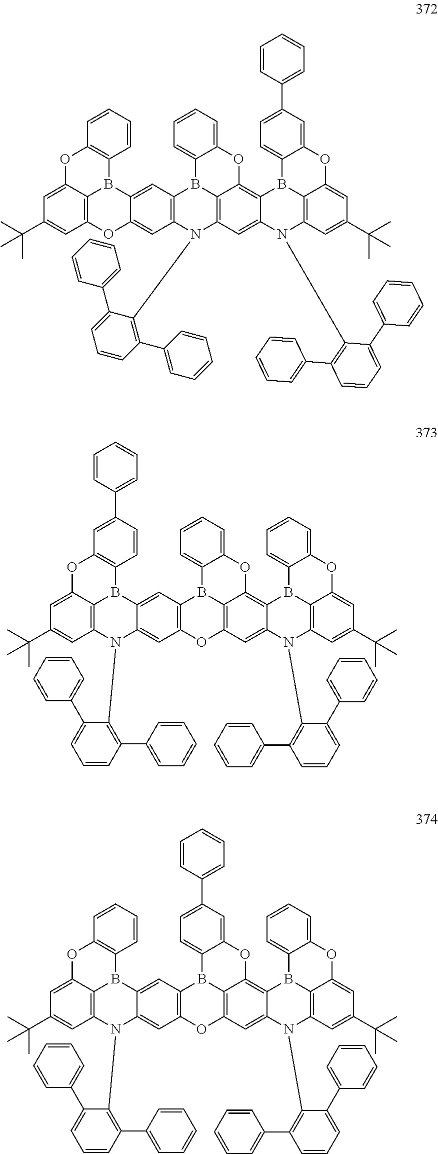 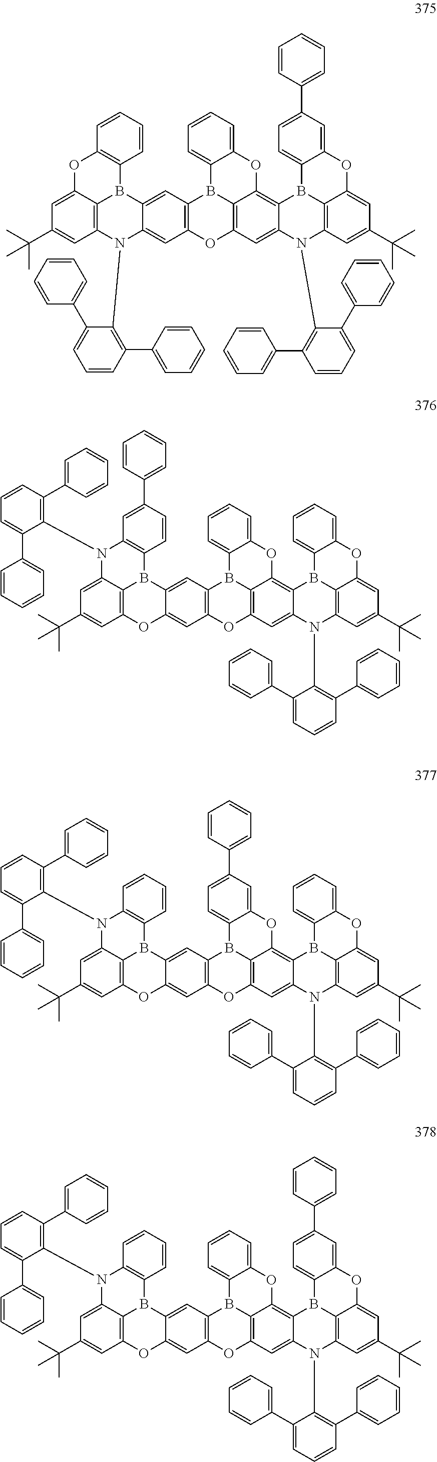 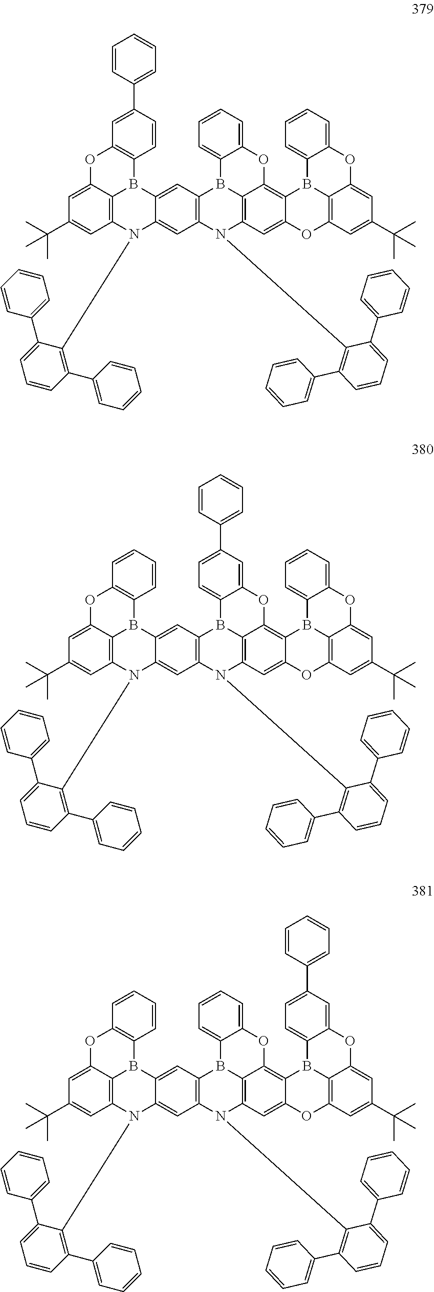 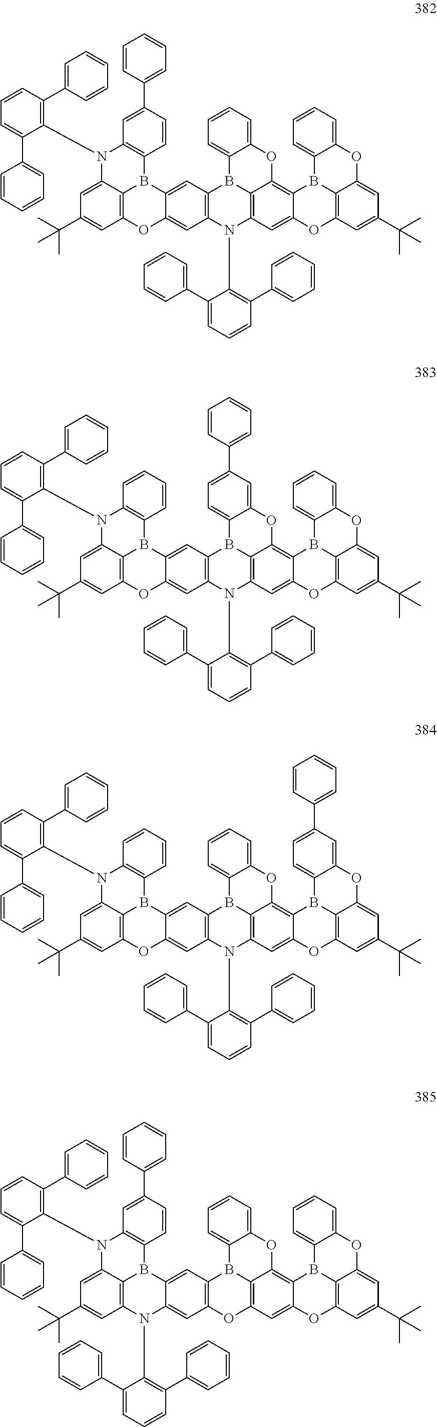 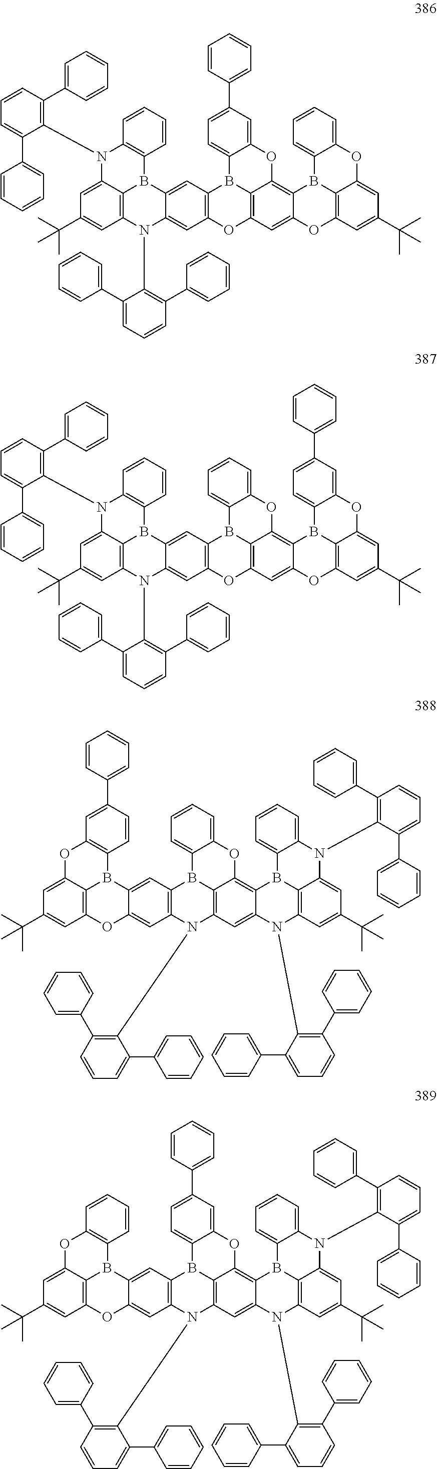 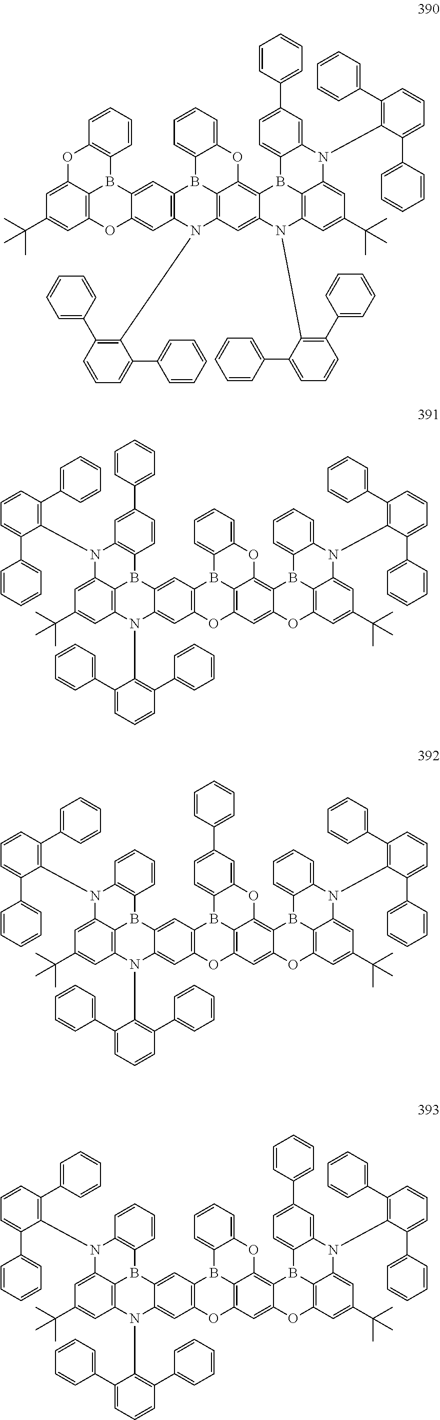 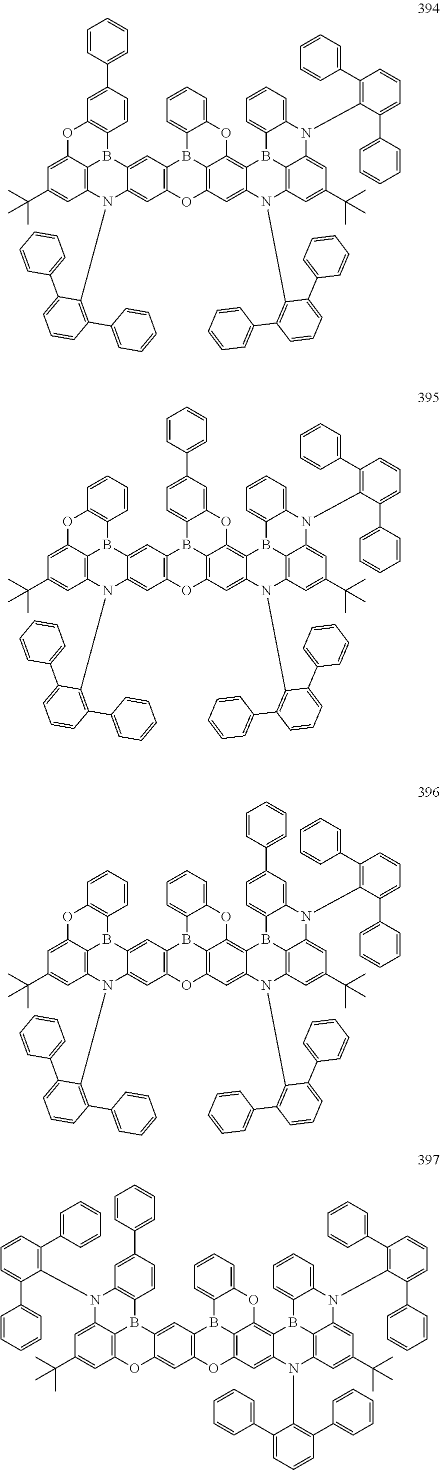 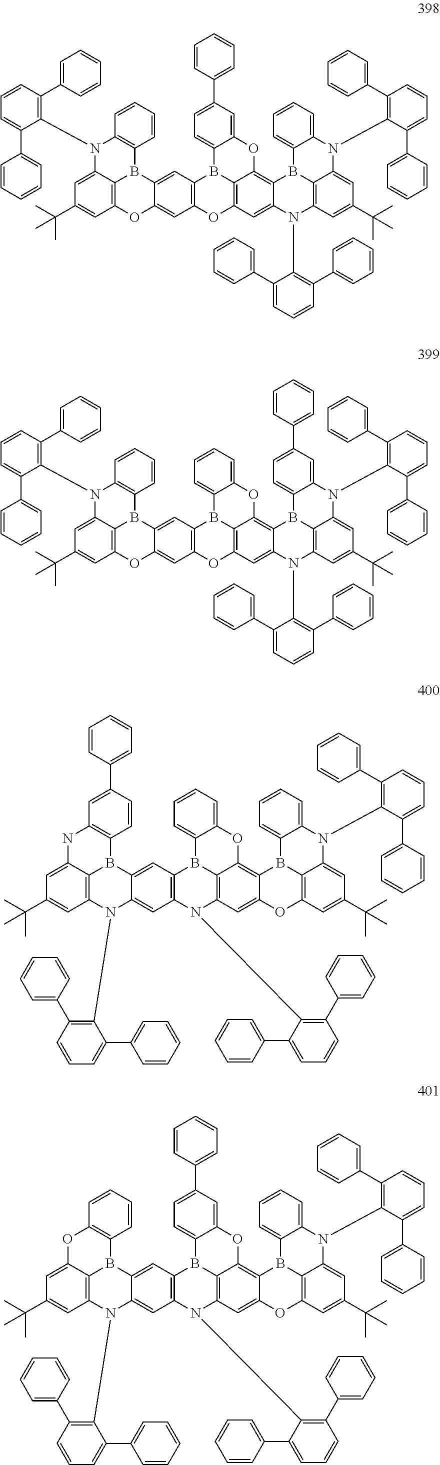 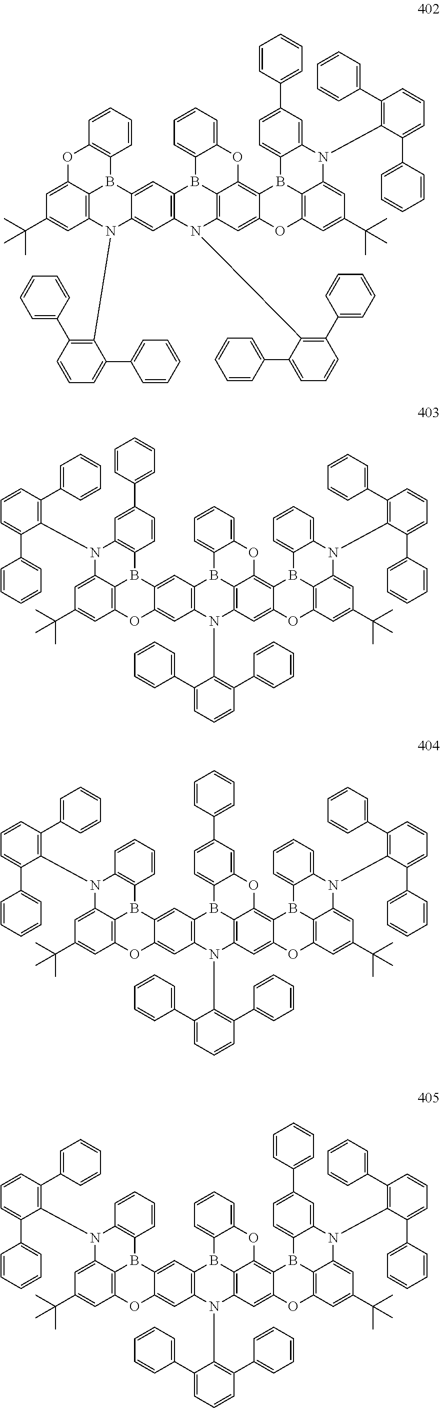 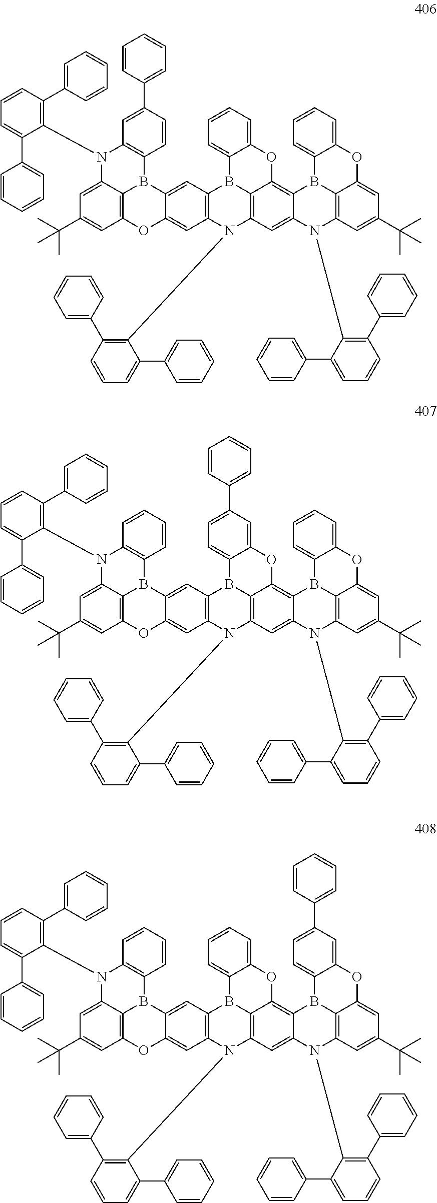 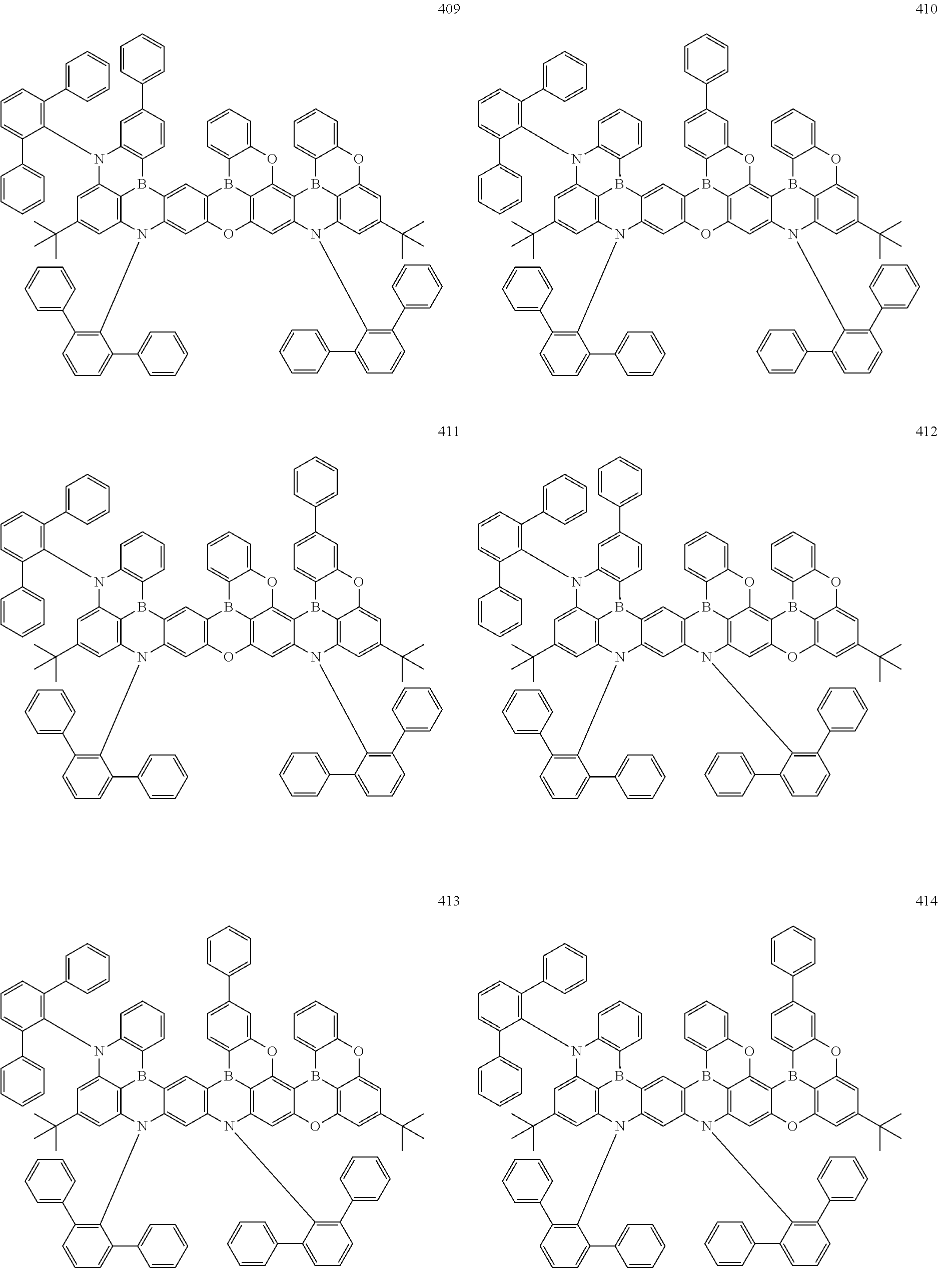 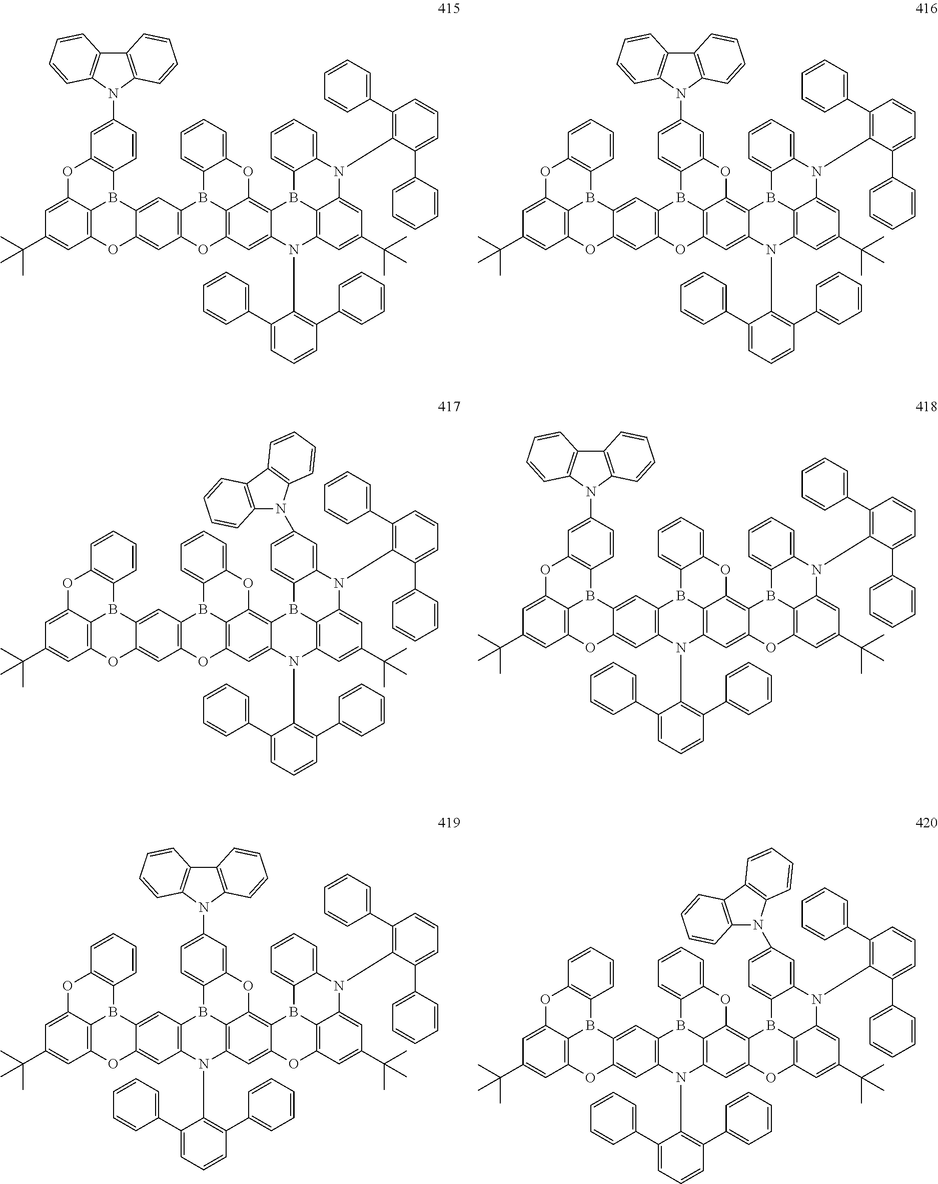 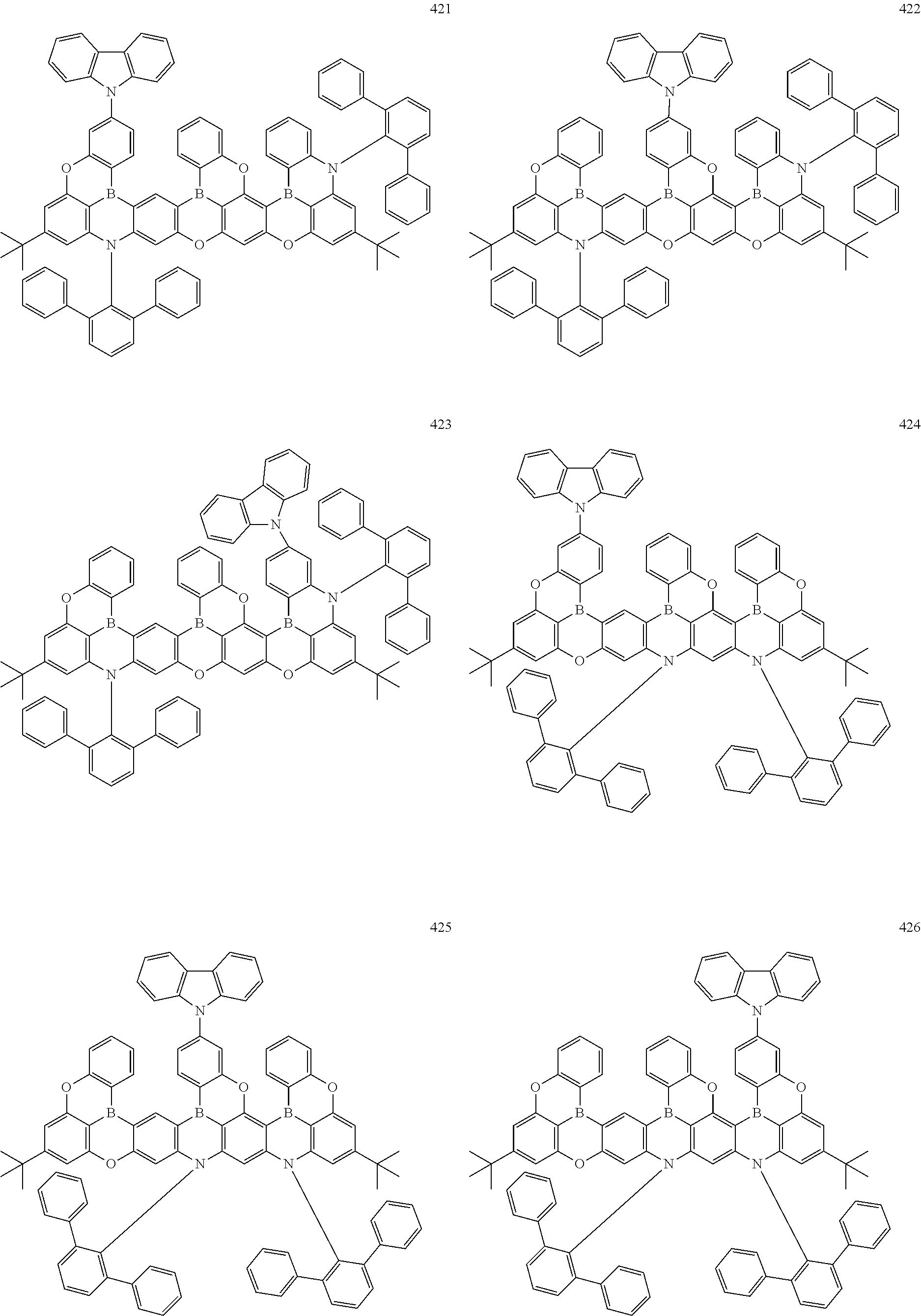 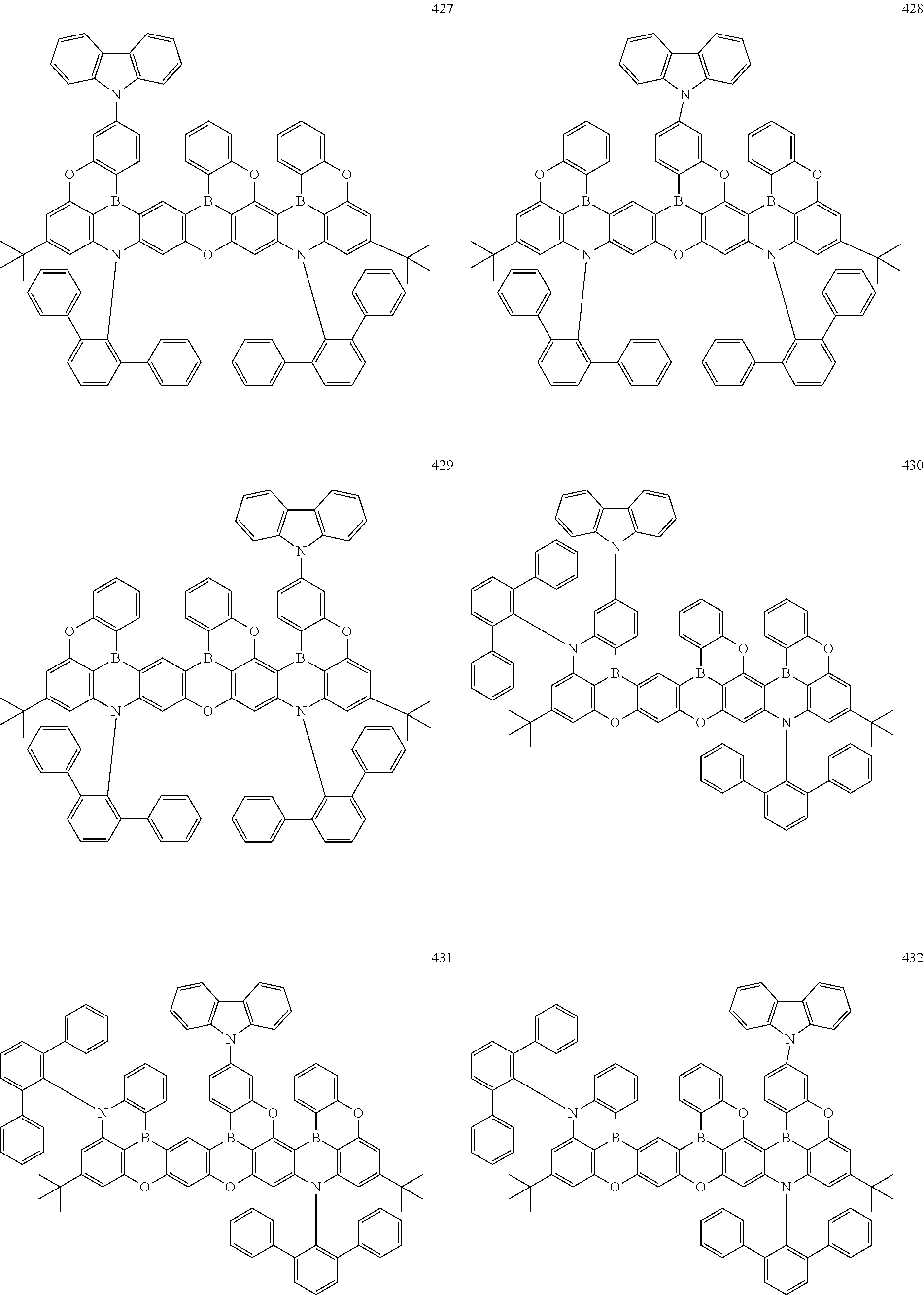 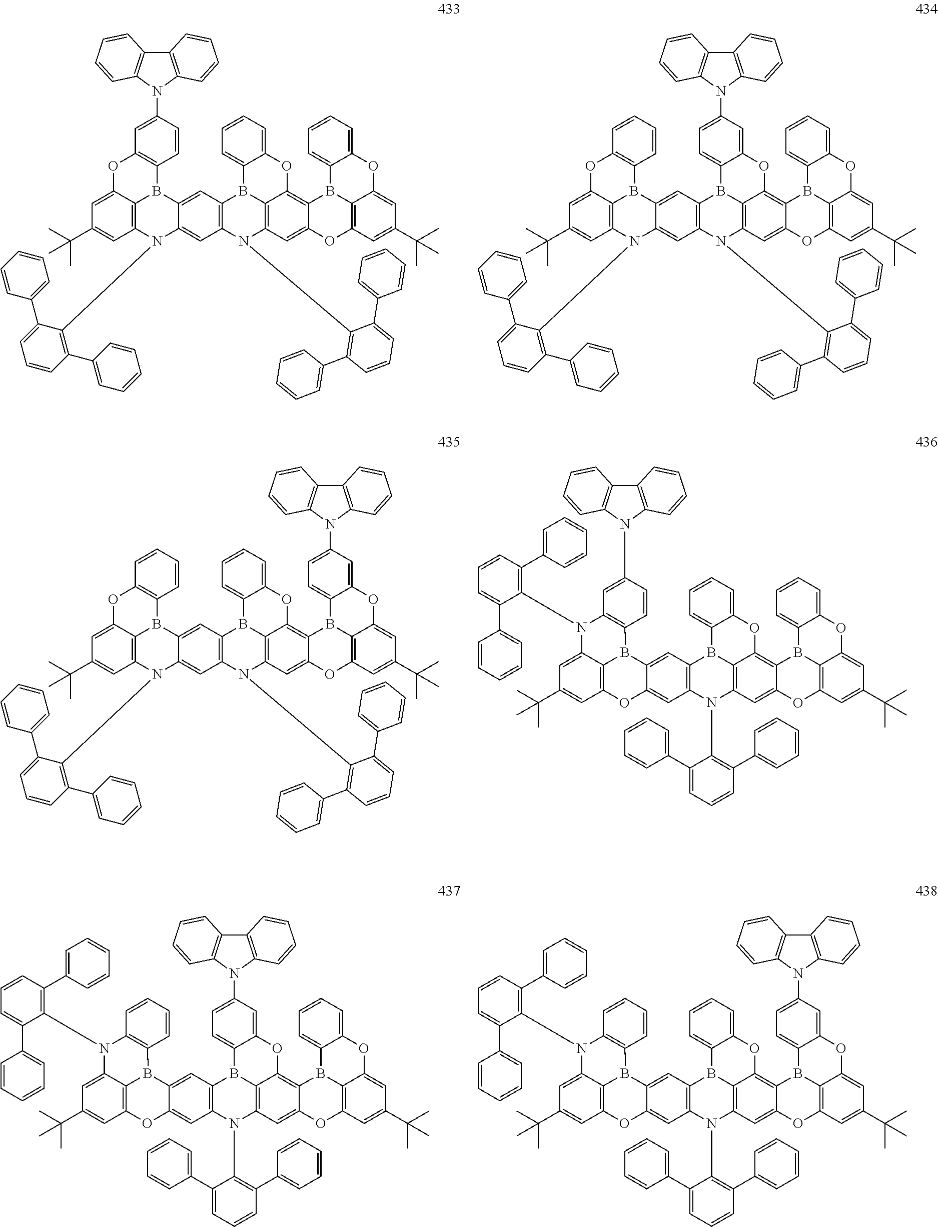 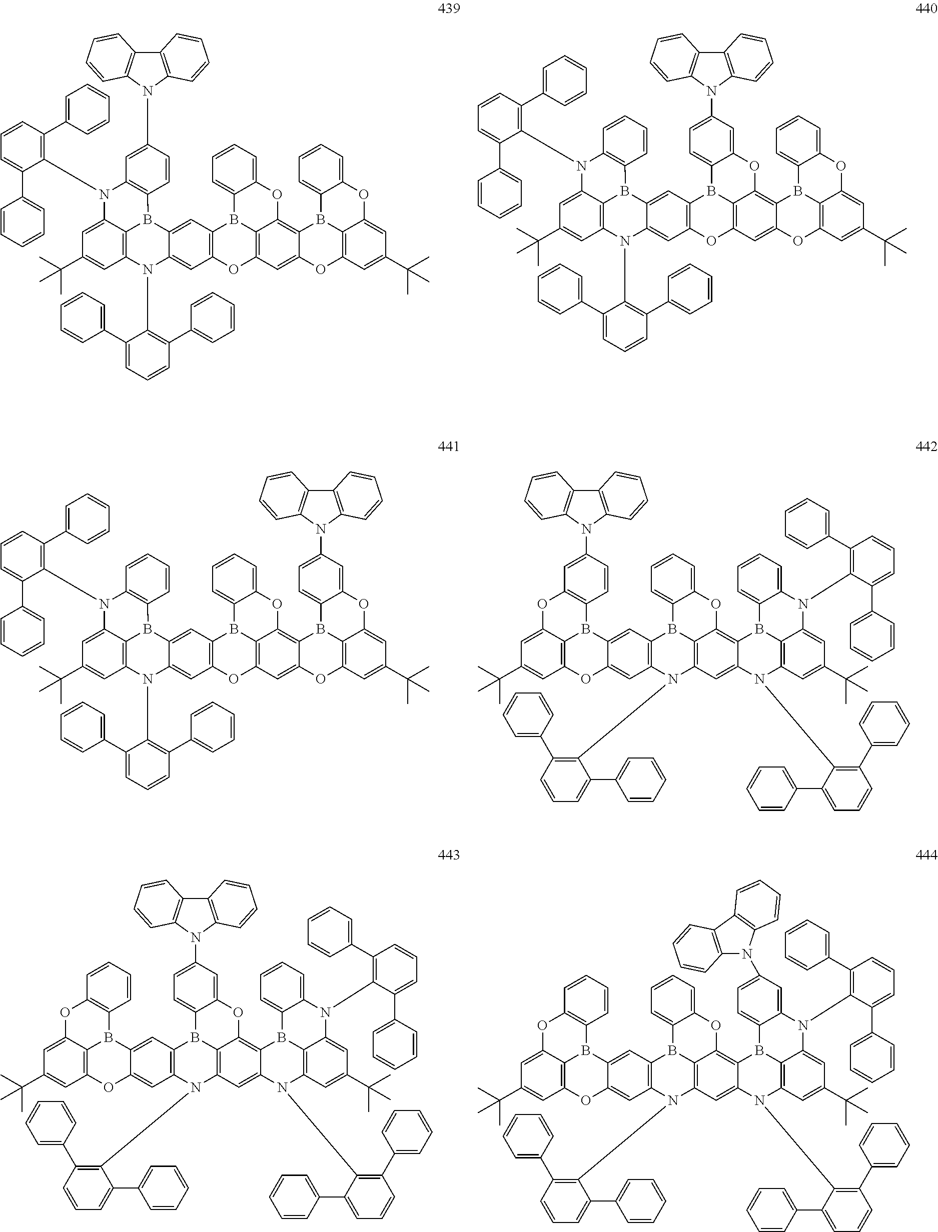 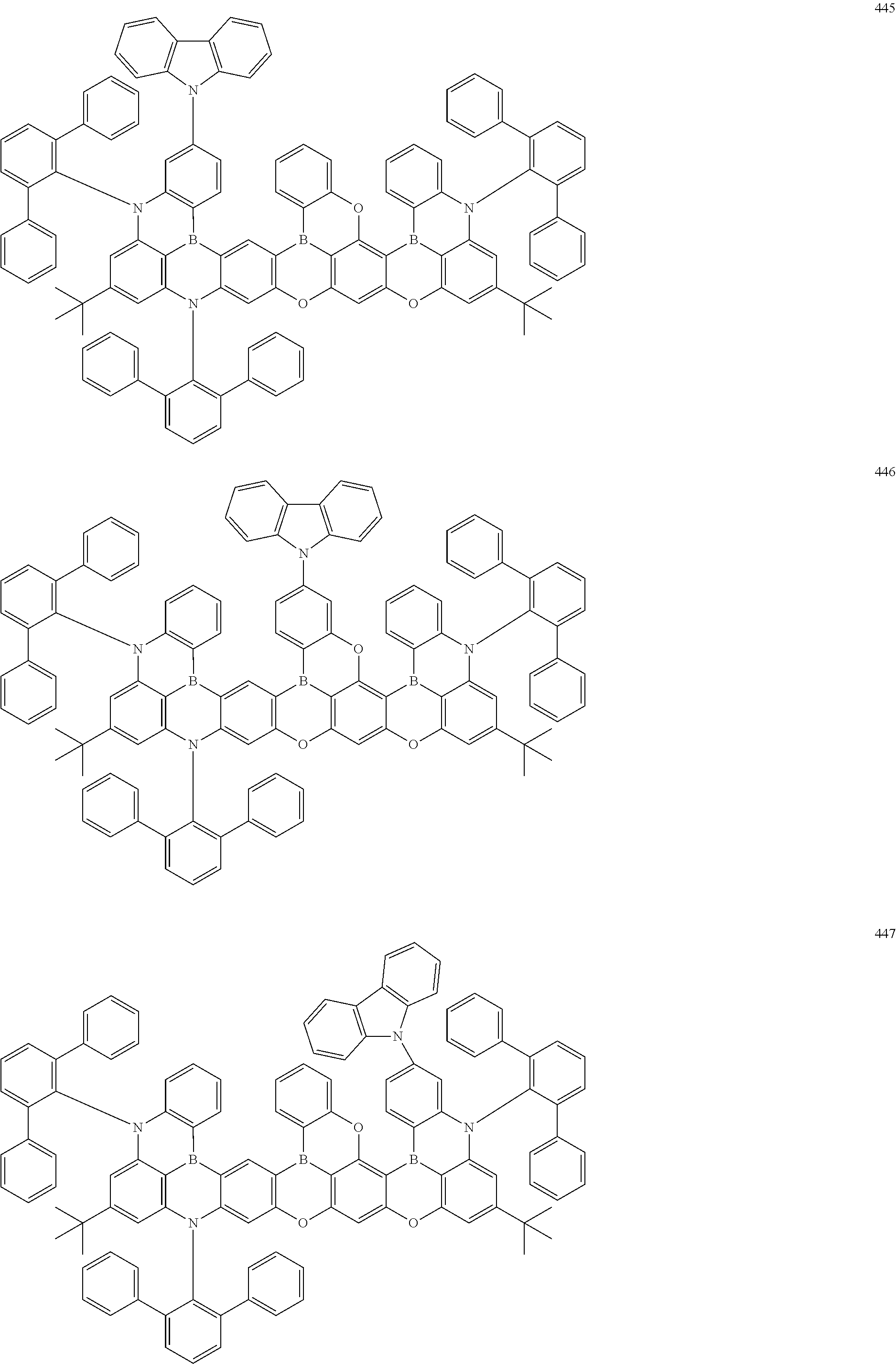 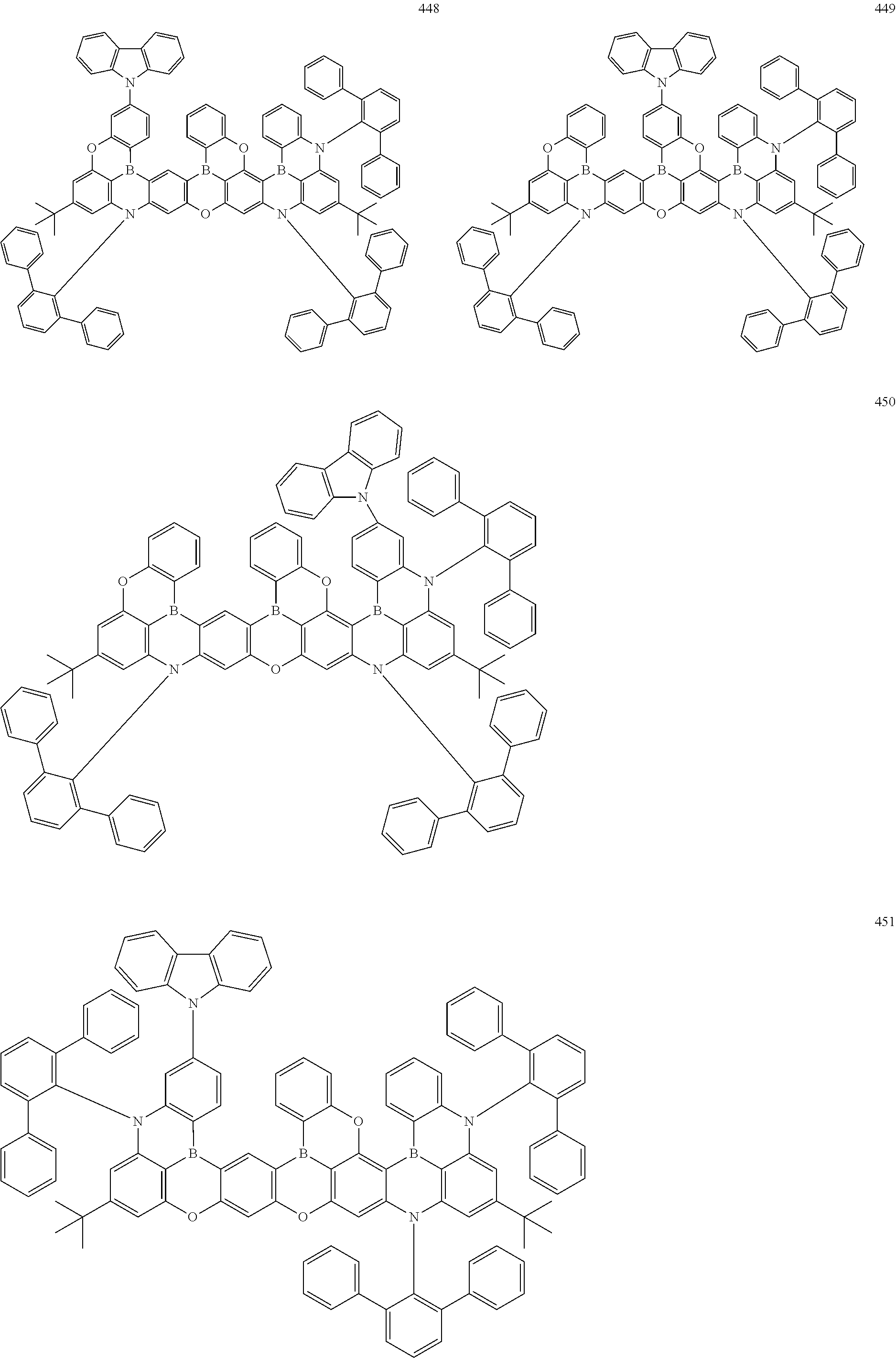 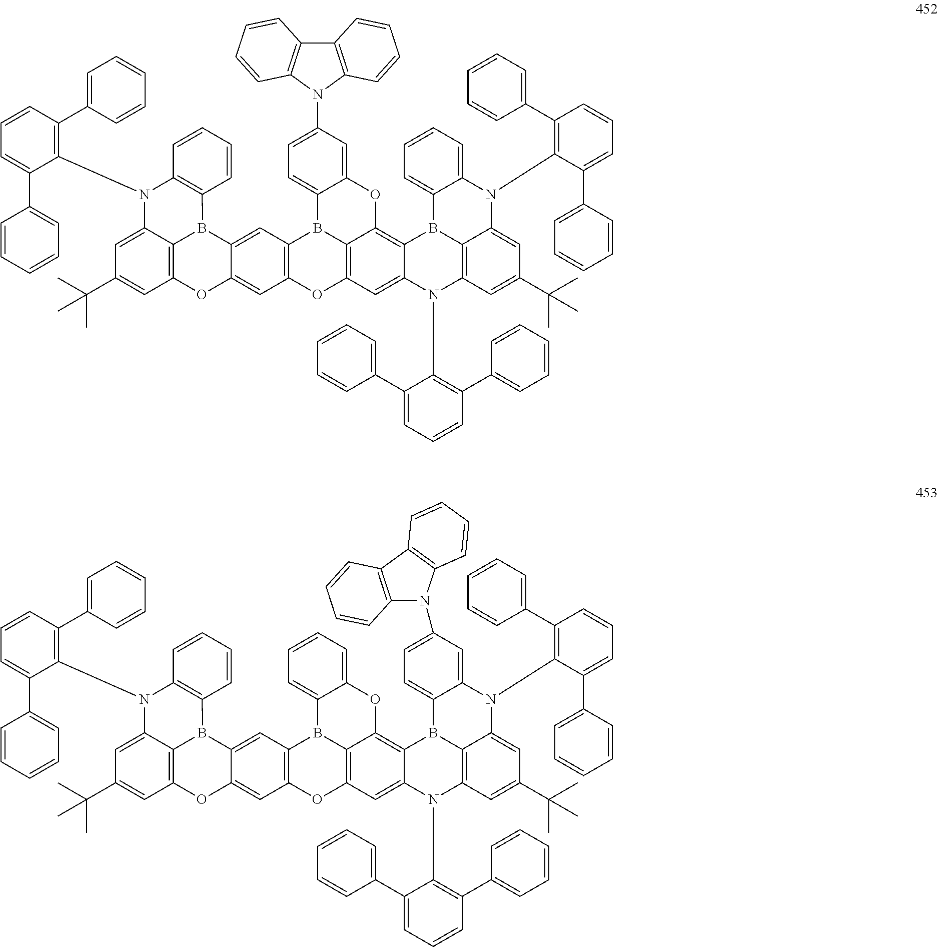 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-n3c5ccccc5c5ccccc53)cc1O4)B1c3ccccc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-n4c5ccccc5c5ccccc54)cc3N(c3c(-c4ccccc4)cccc3-c3ccccc3)c3cc(C(C)(C)C)cc(c31)N2c1c(-c2ccccc2)cccc1-c1ccccc1] 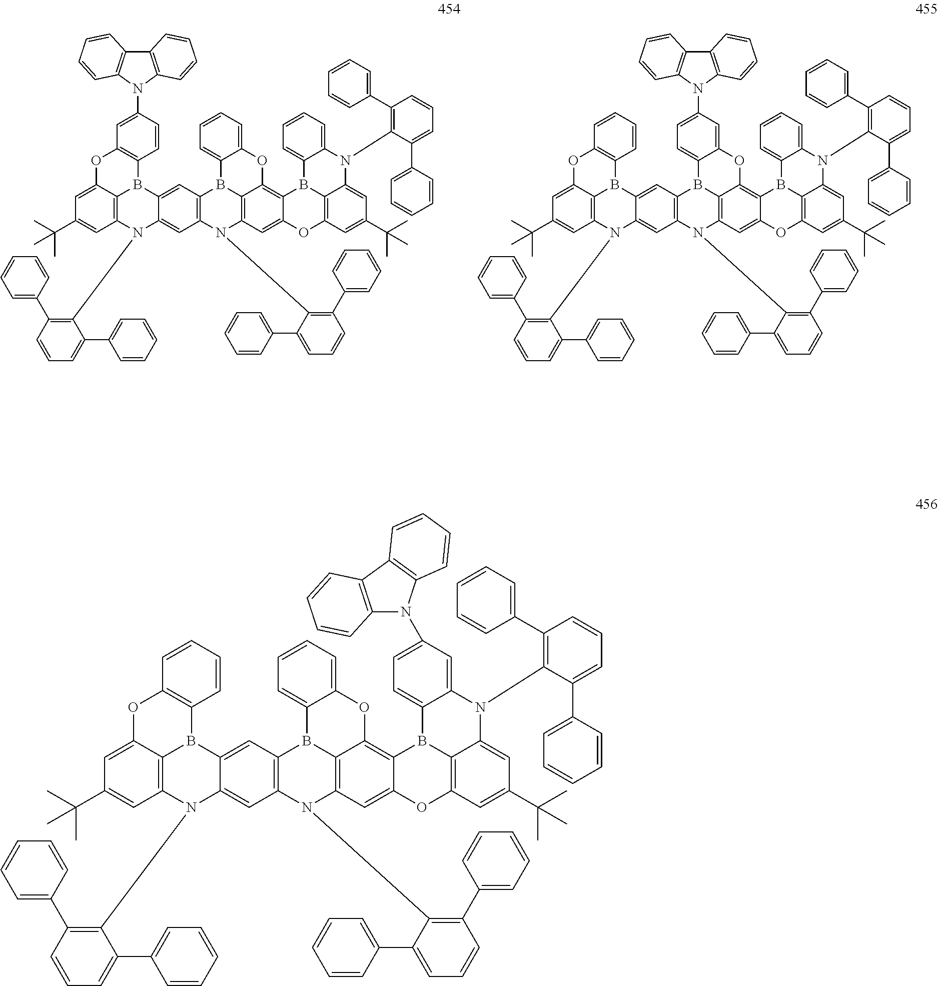 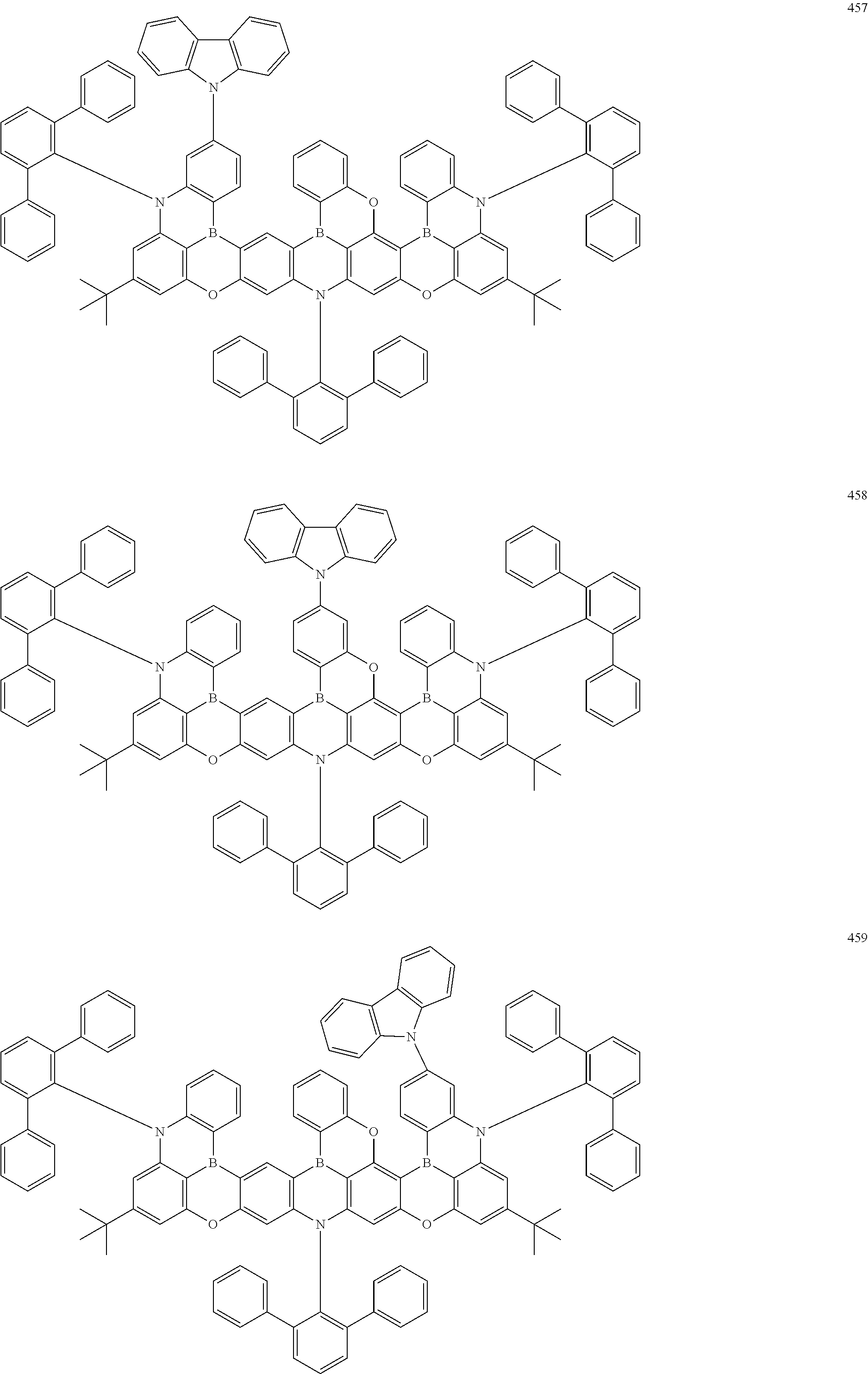 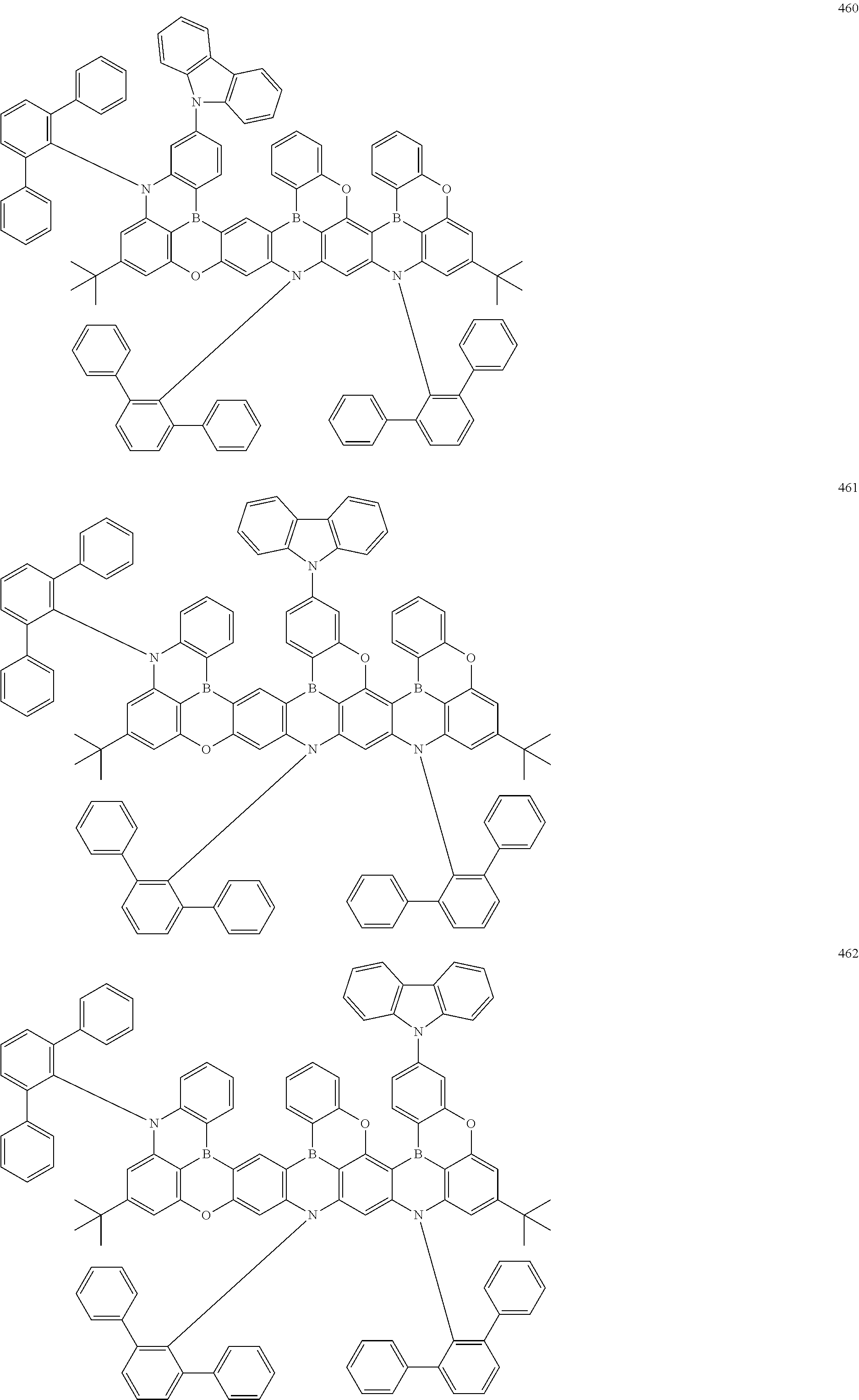 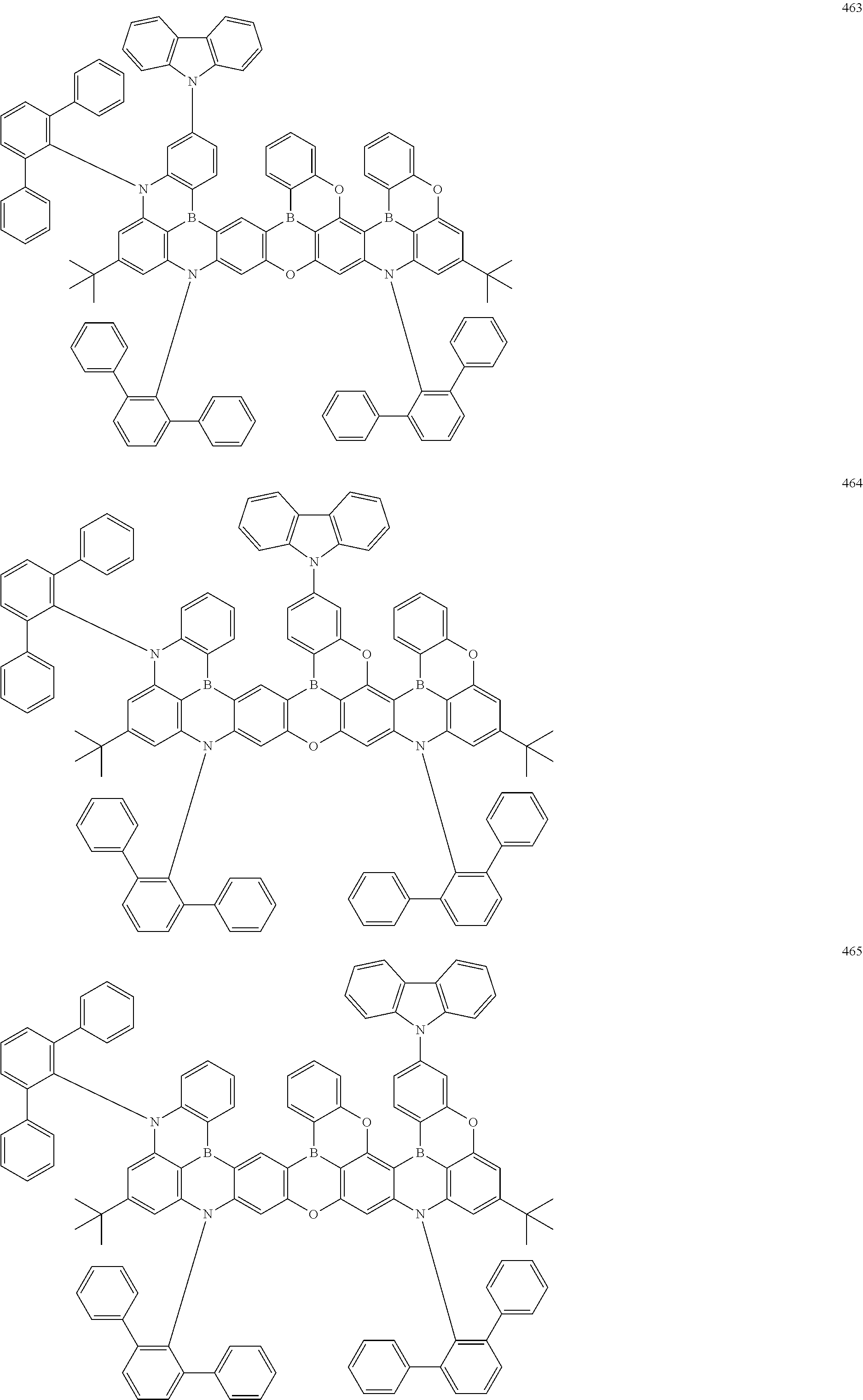 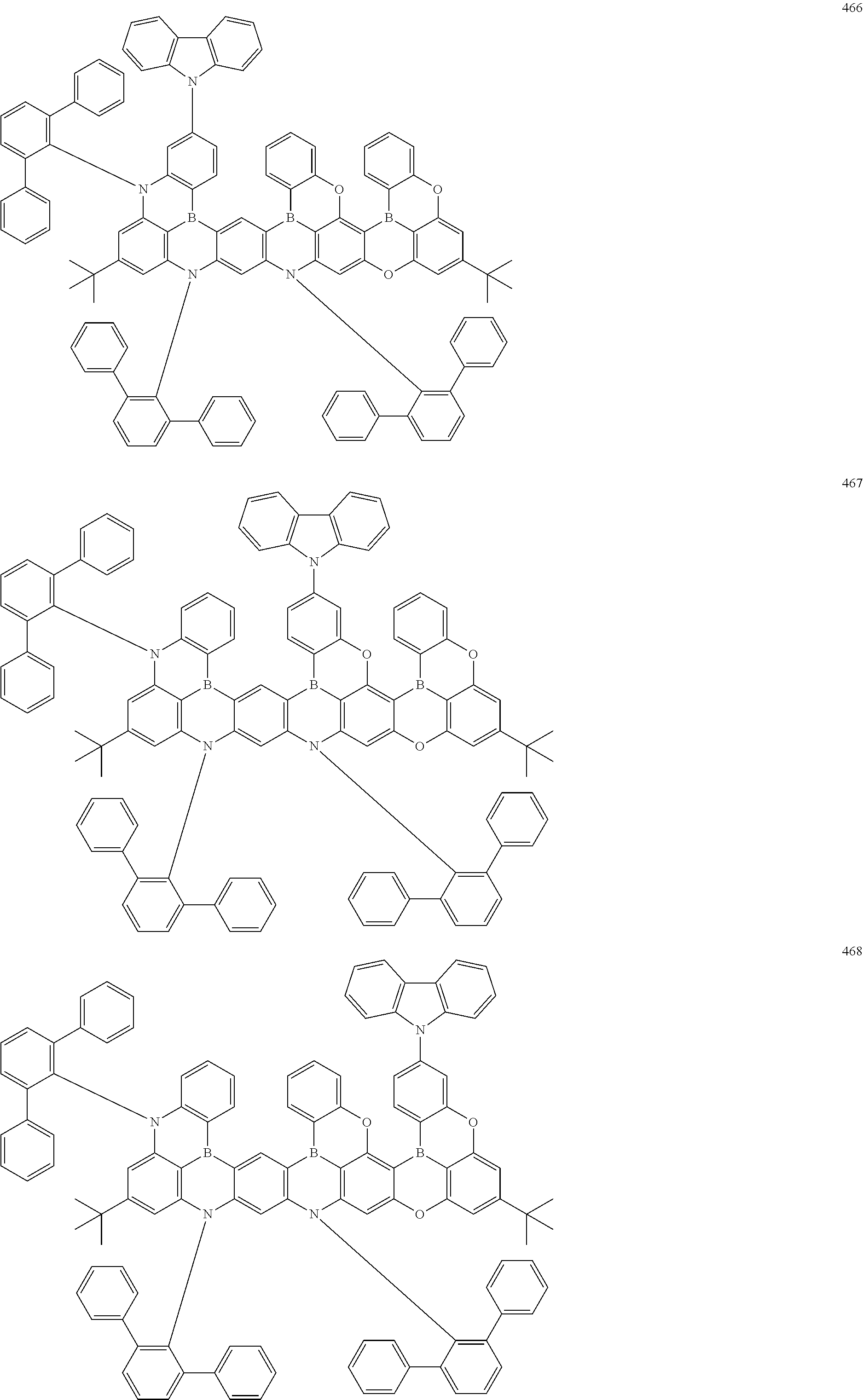 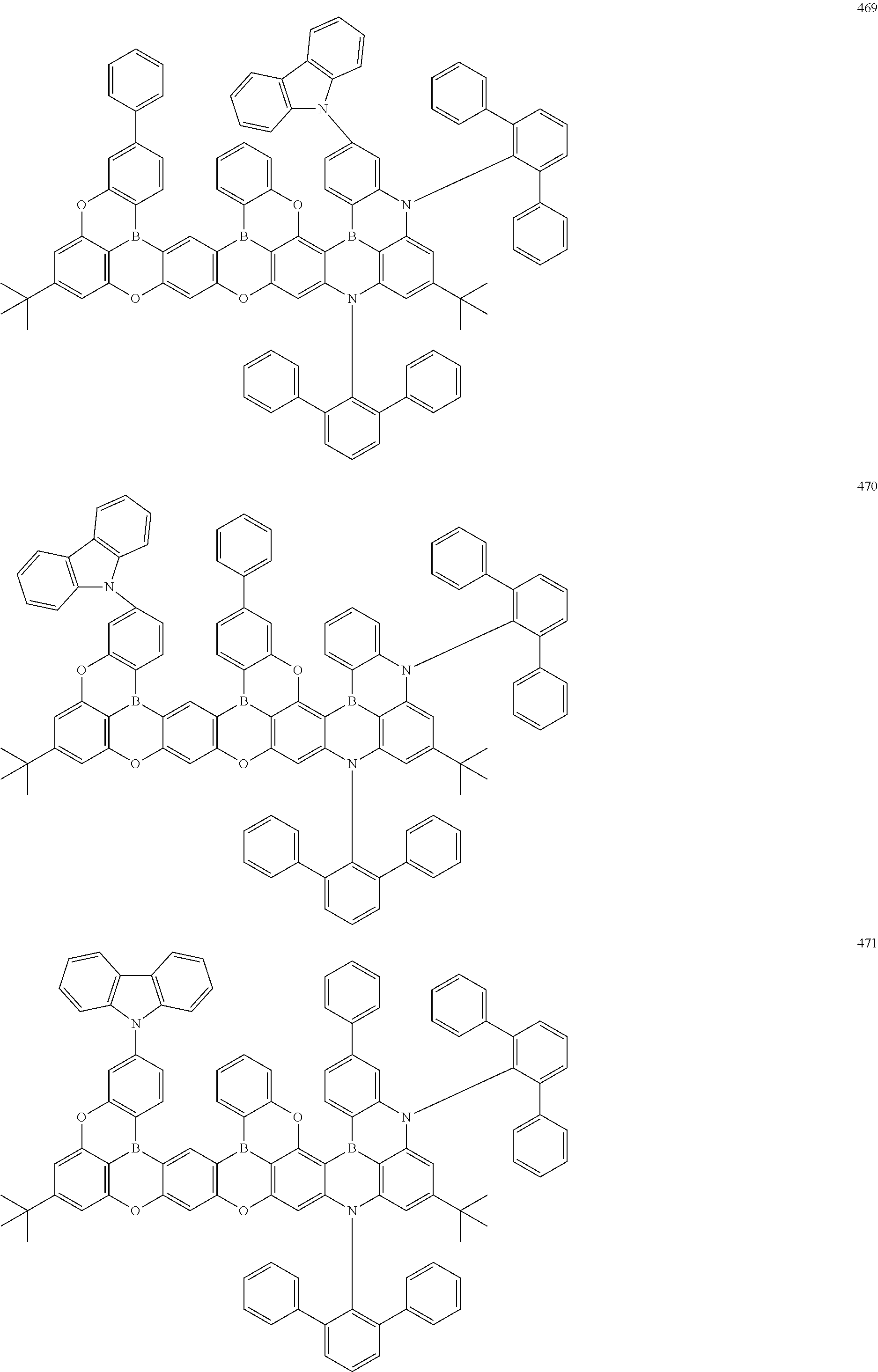 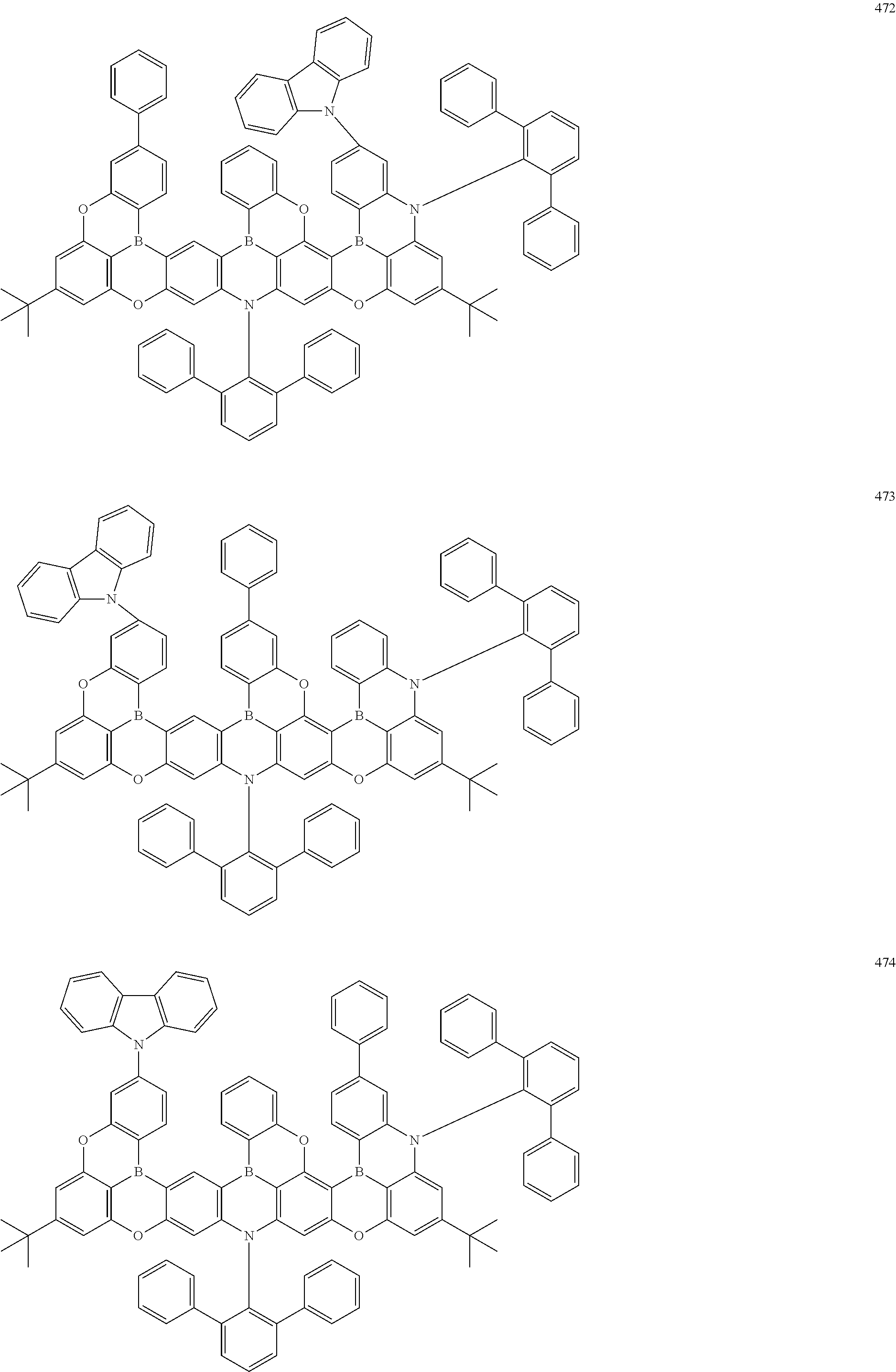 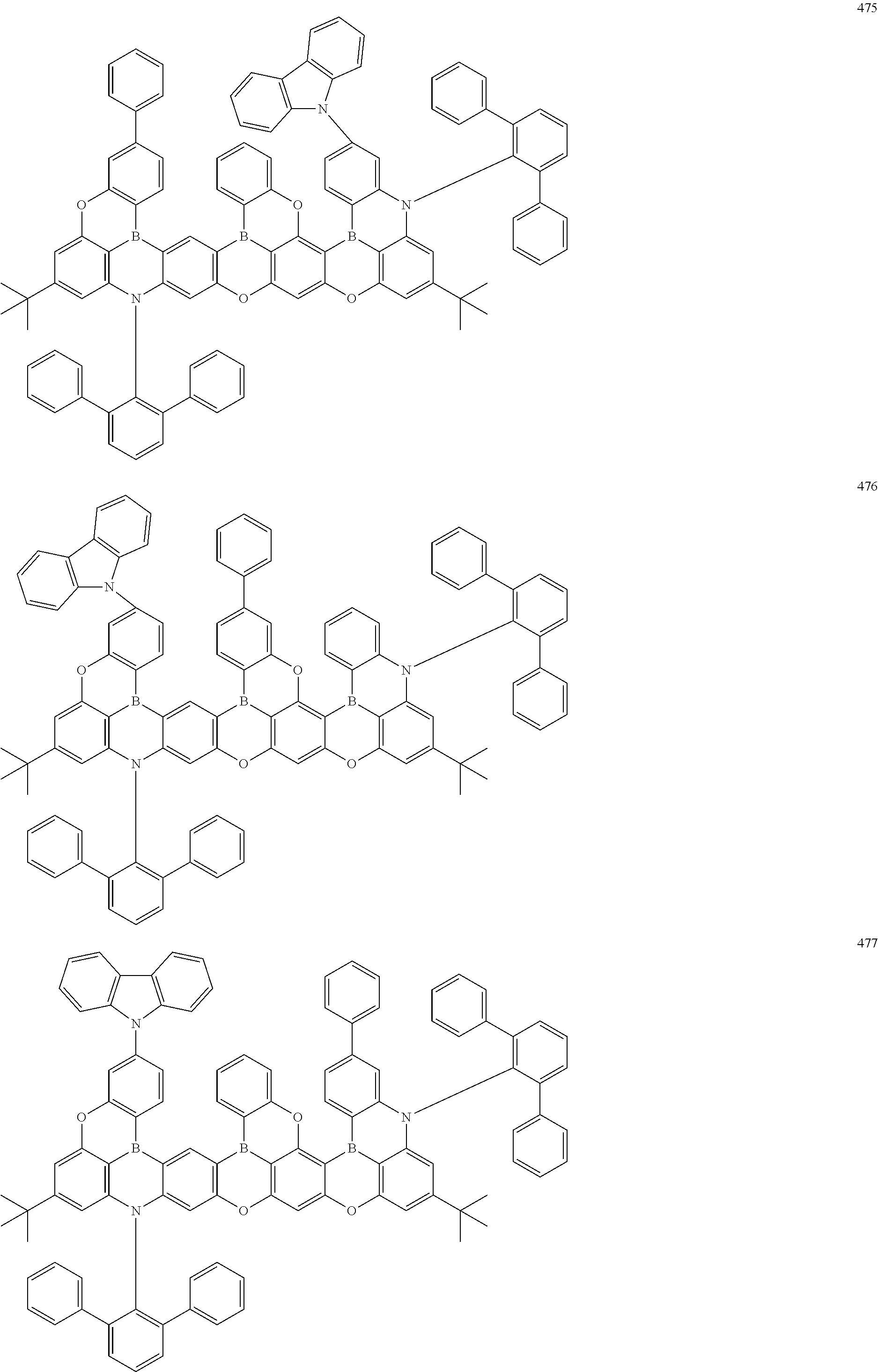 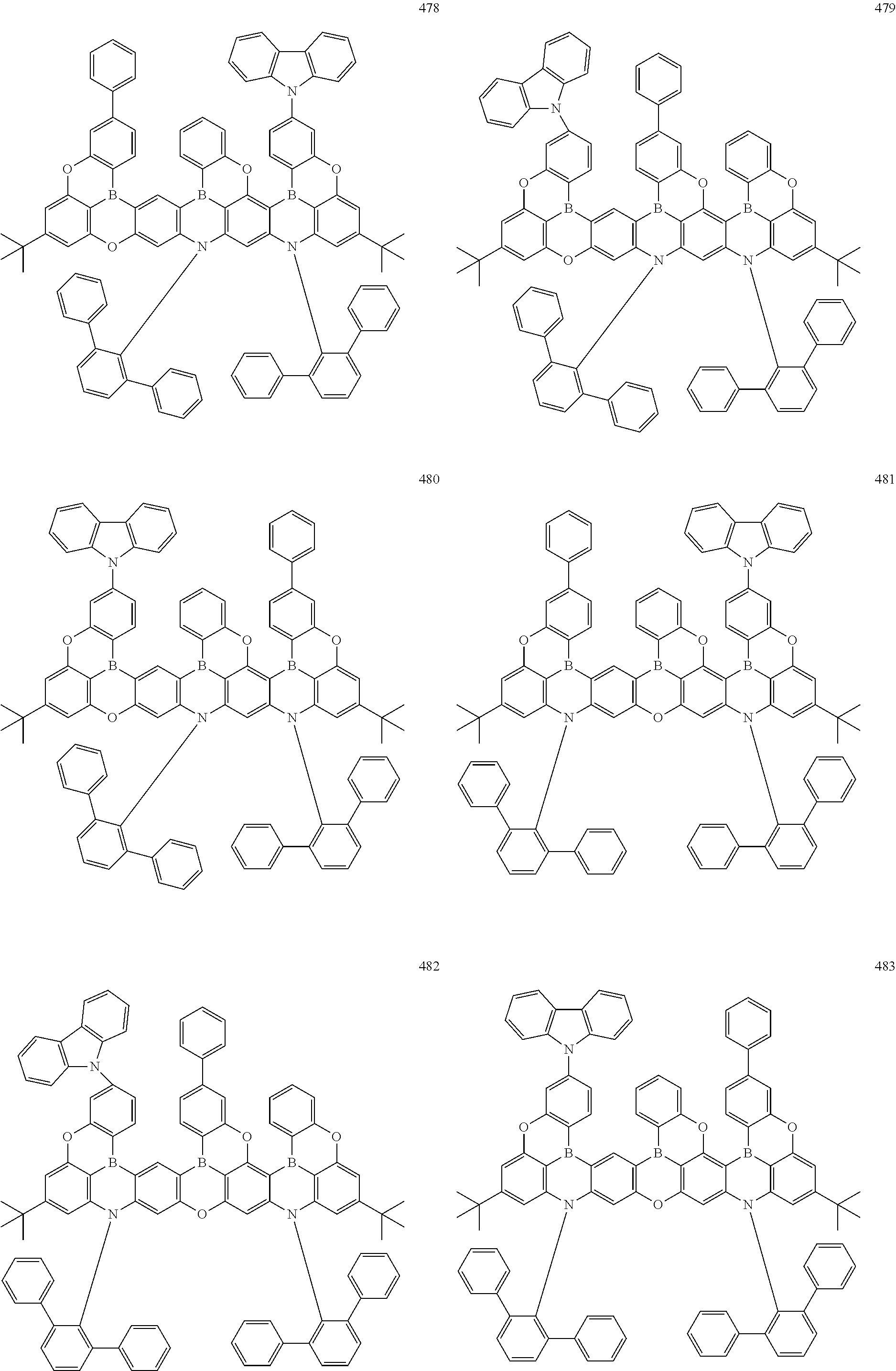 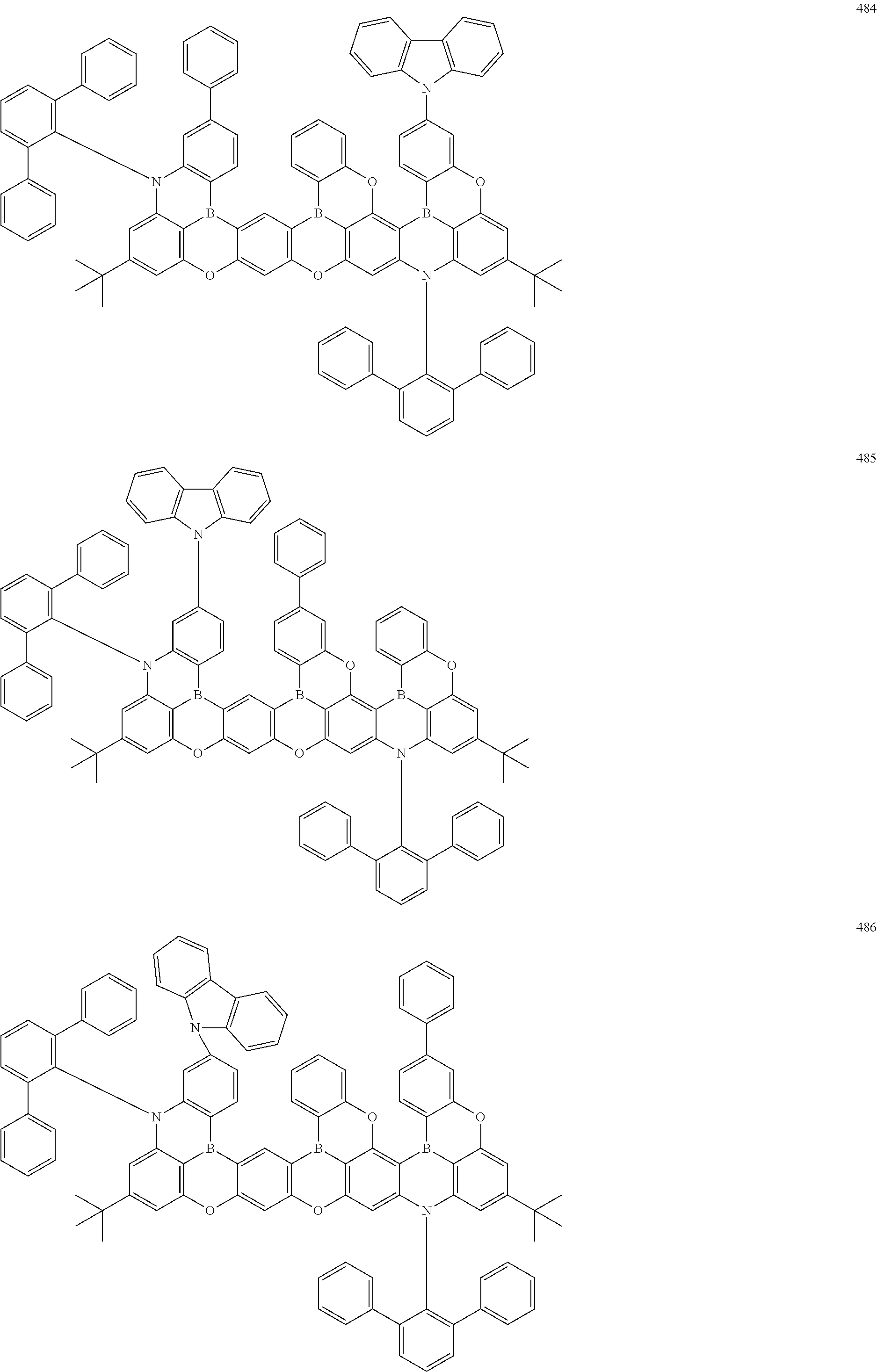 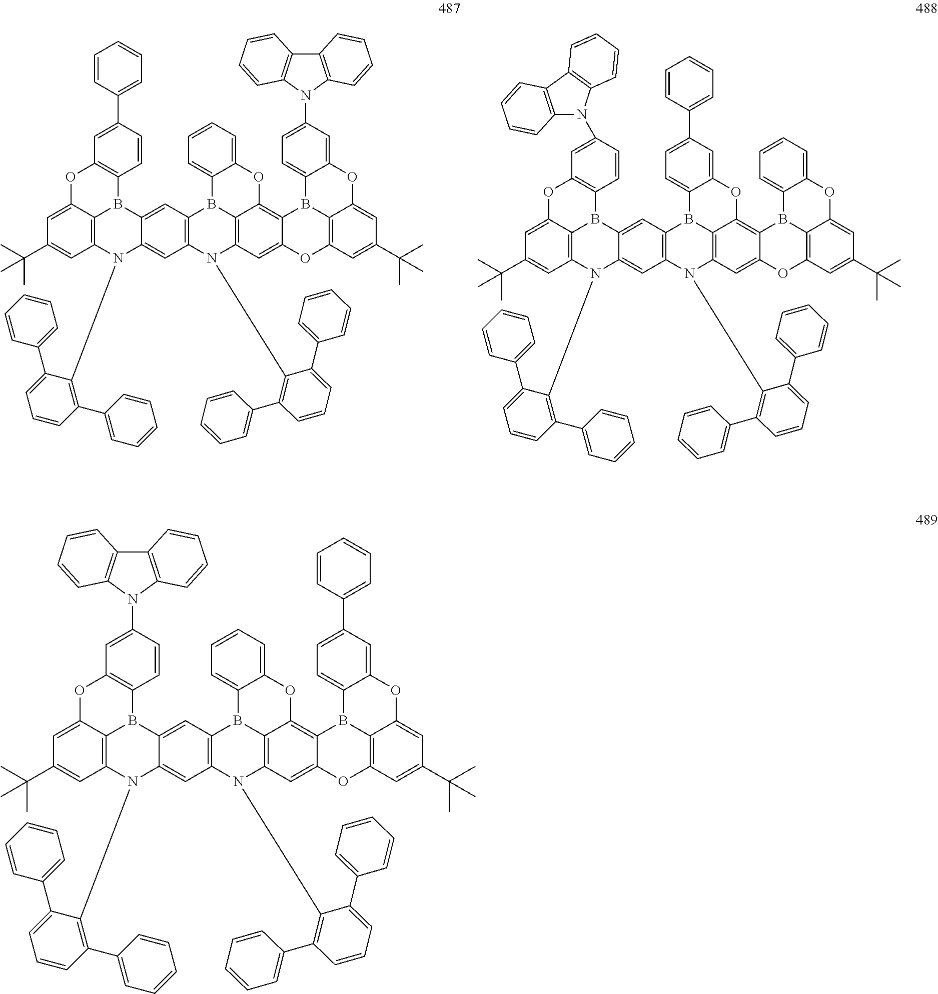 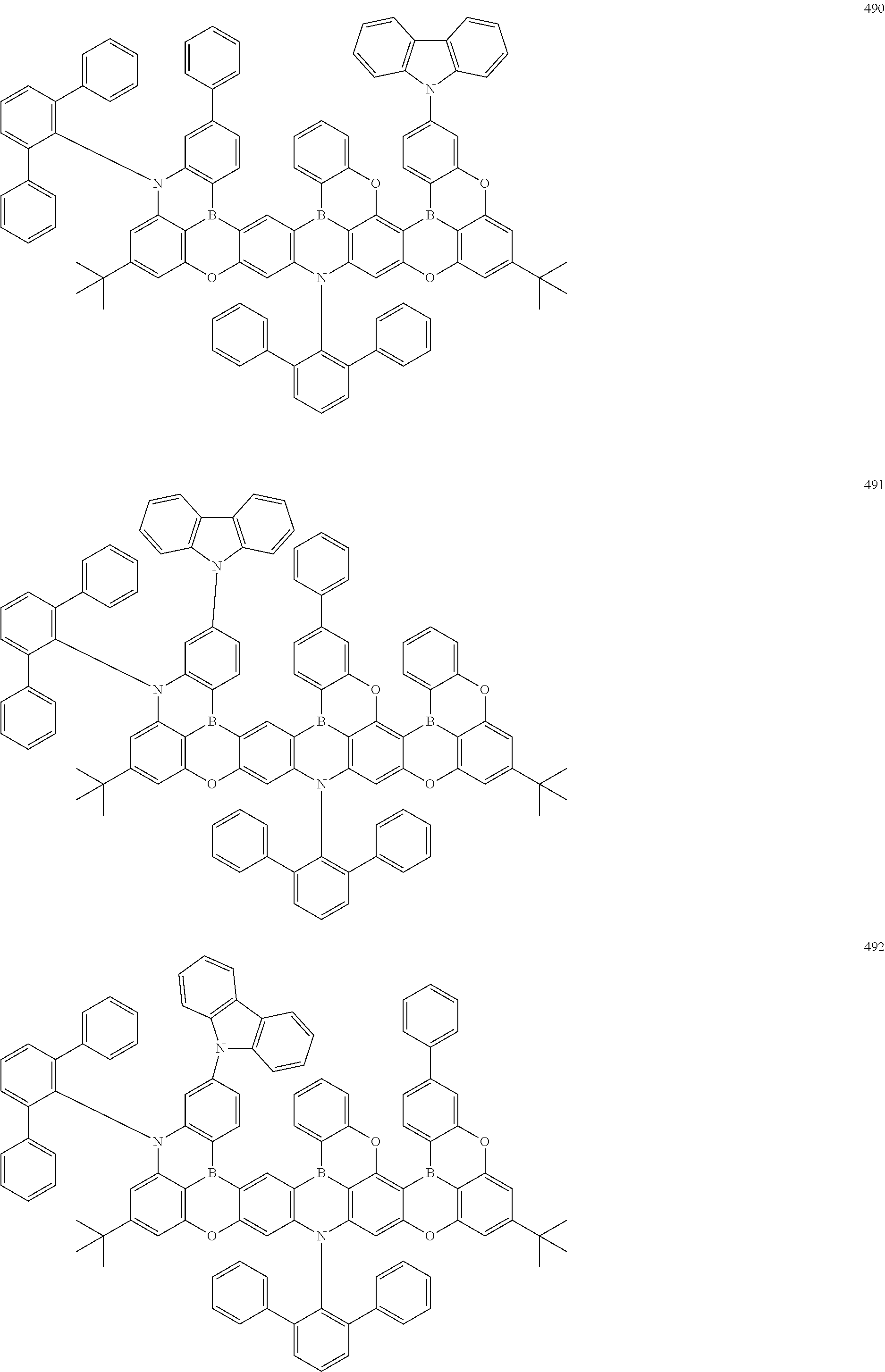 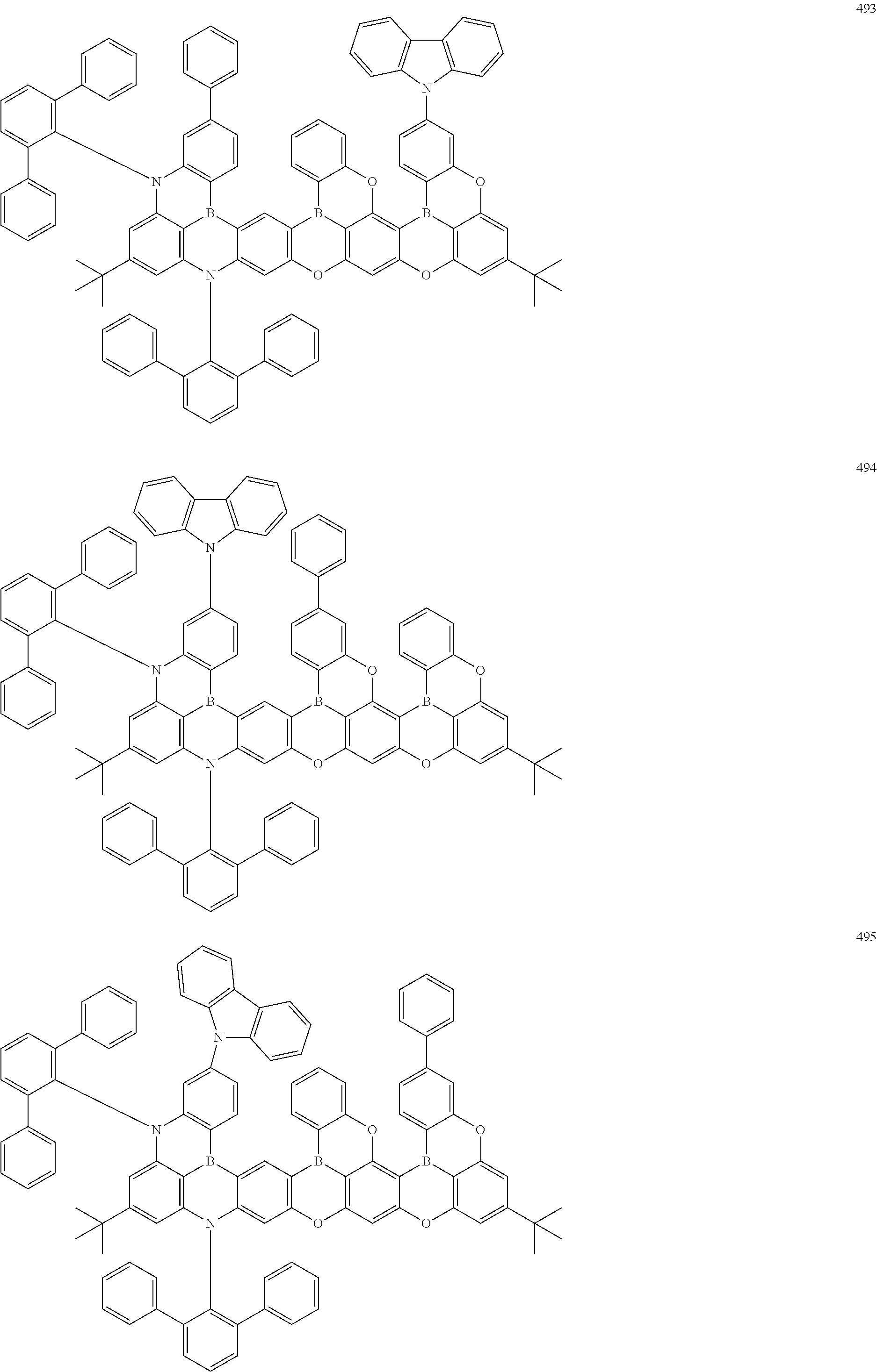 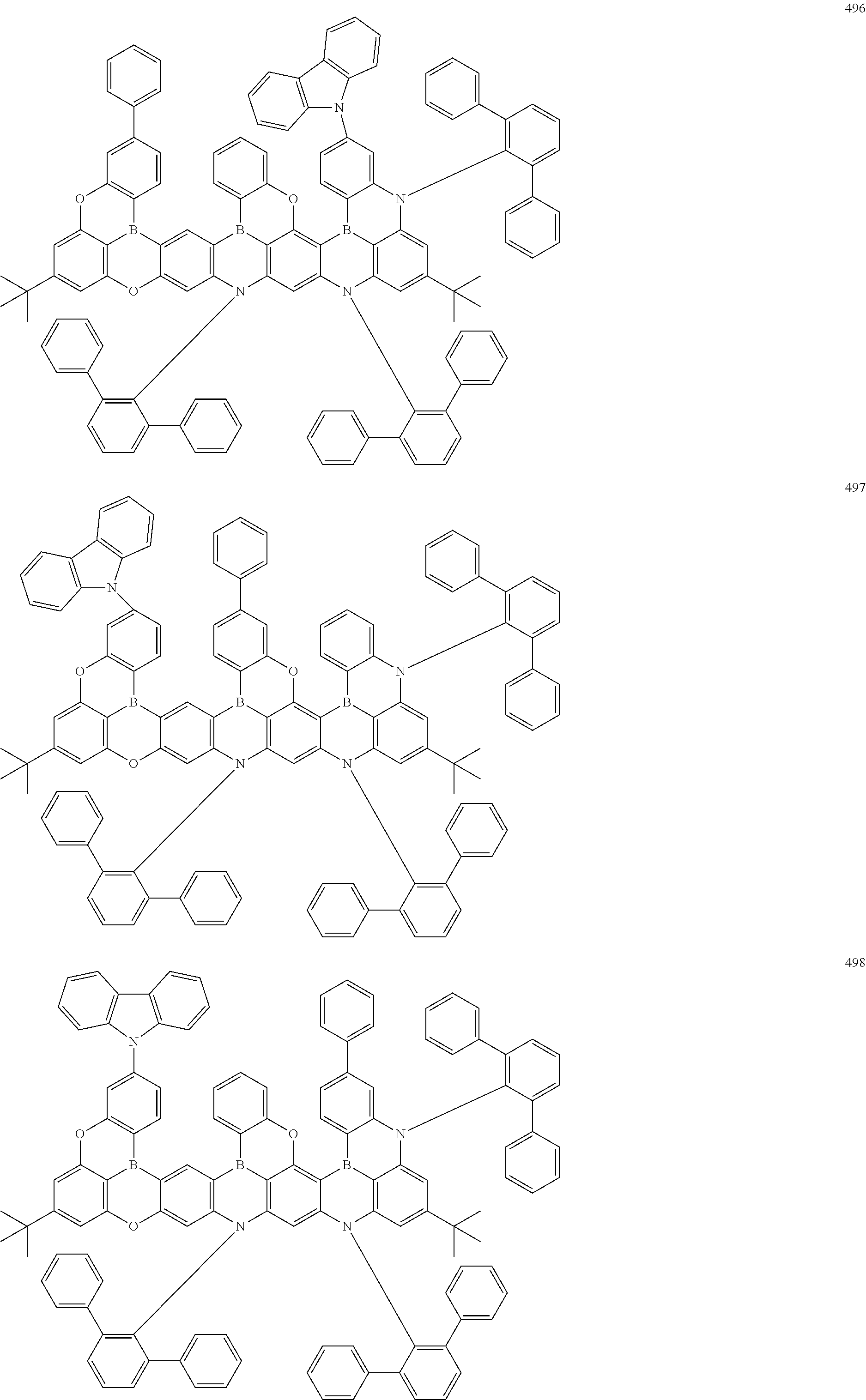 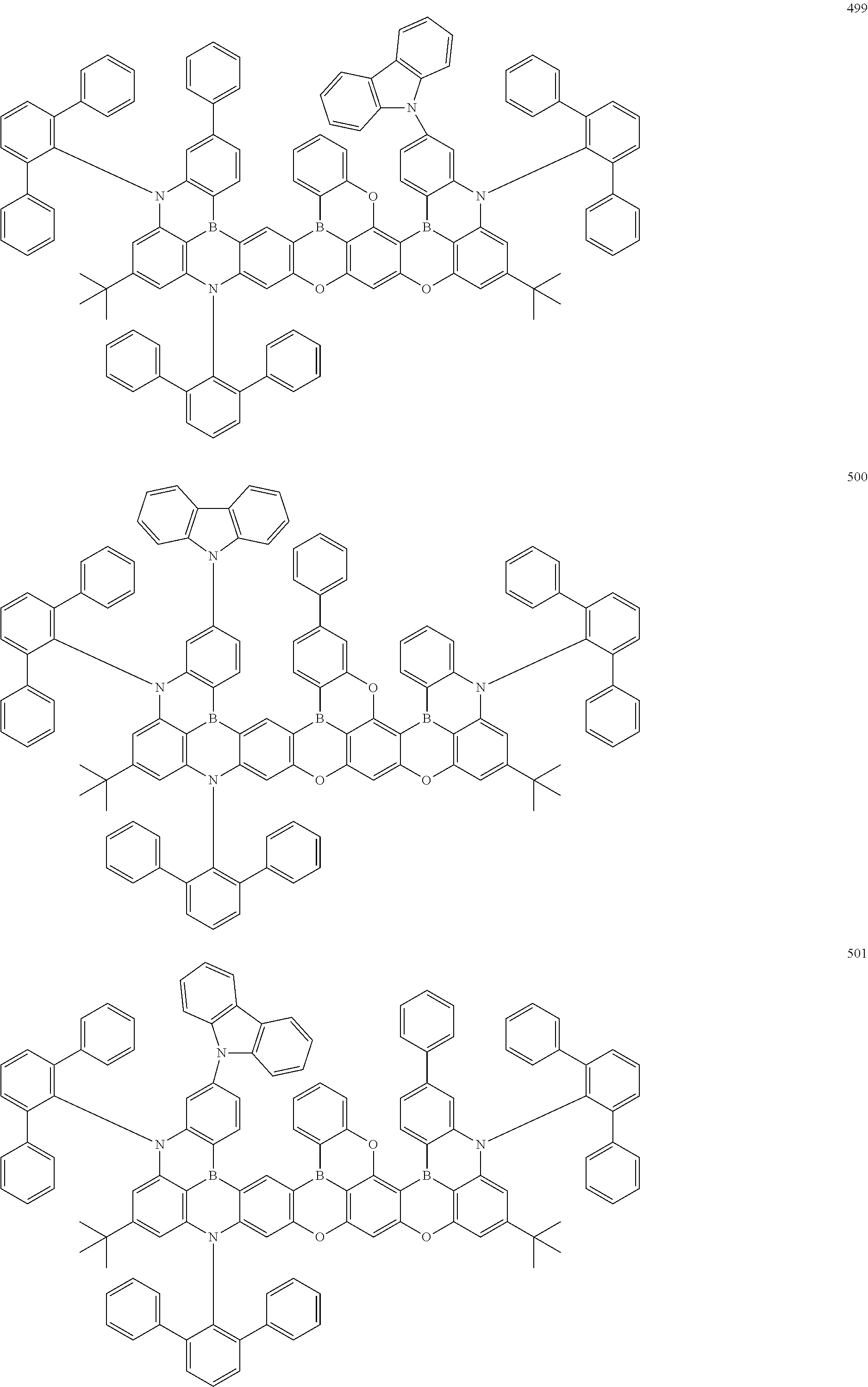 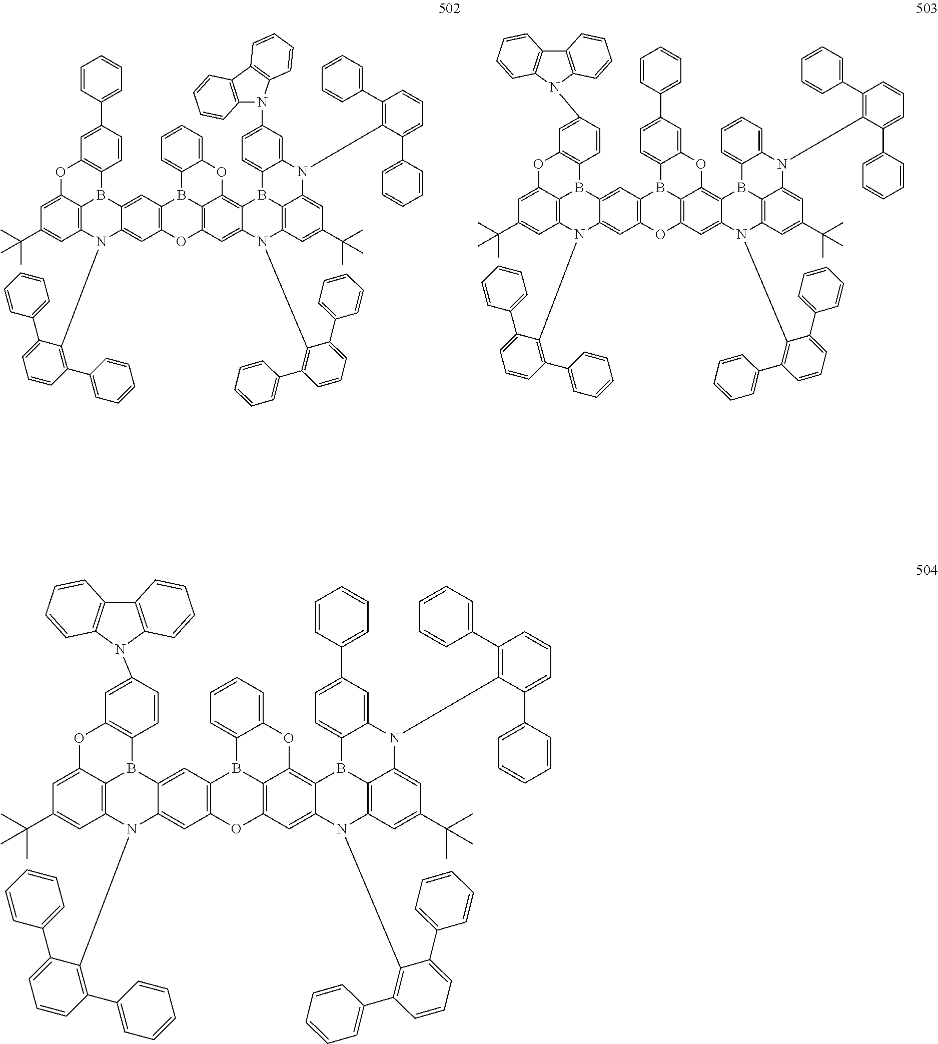 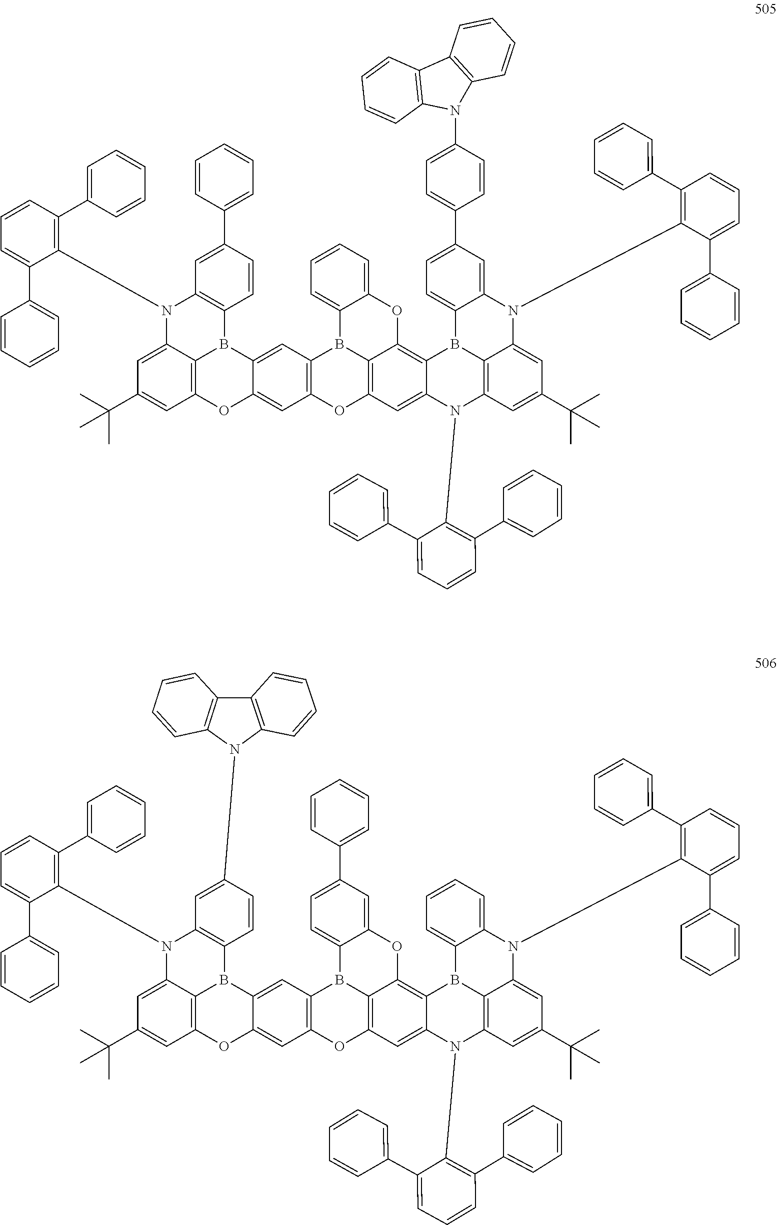 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccc(-c4ccc(-n5c6ccccc6c6ccccc65)cc4)cc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)N2c1c(-c2ccccc2)cccc1-c1ccccc1] 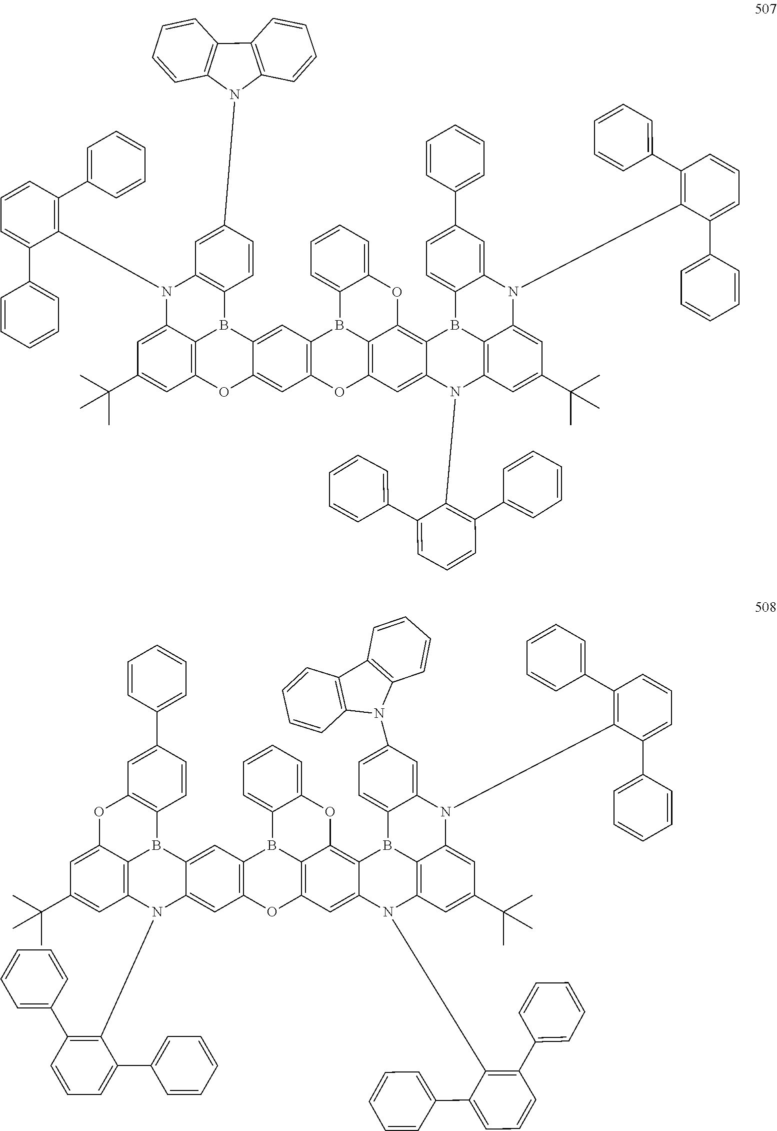 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccc(-n5c6ccccc6c6ccccc65)cc3N(c3c(-c5ccccc5)cccc3-c3ccccc3)c3cc(C(C)(C)C)cc(c32)N1c1c(-c2ccccc2)cccc1-c1ccccc1)O4] 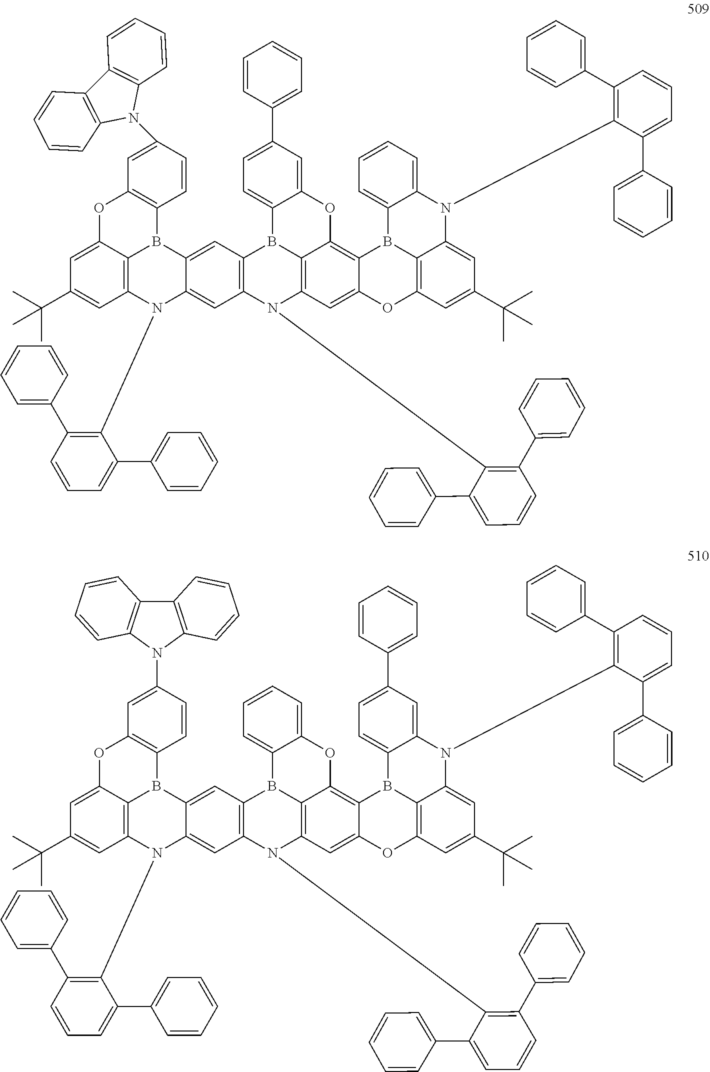 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1] 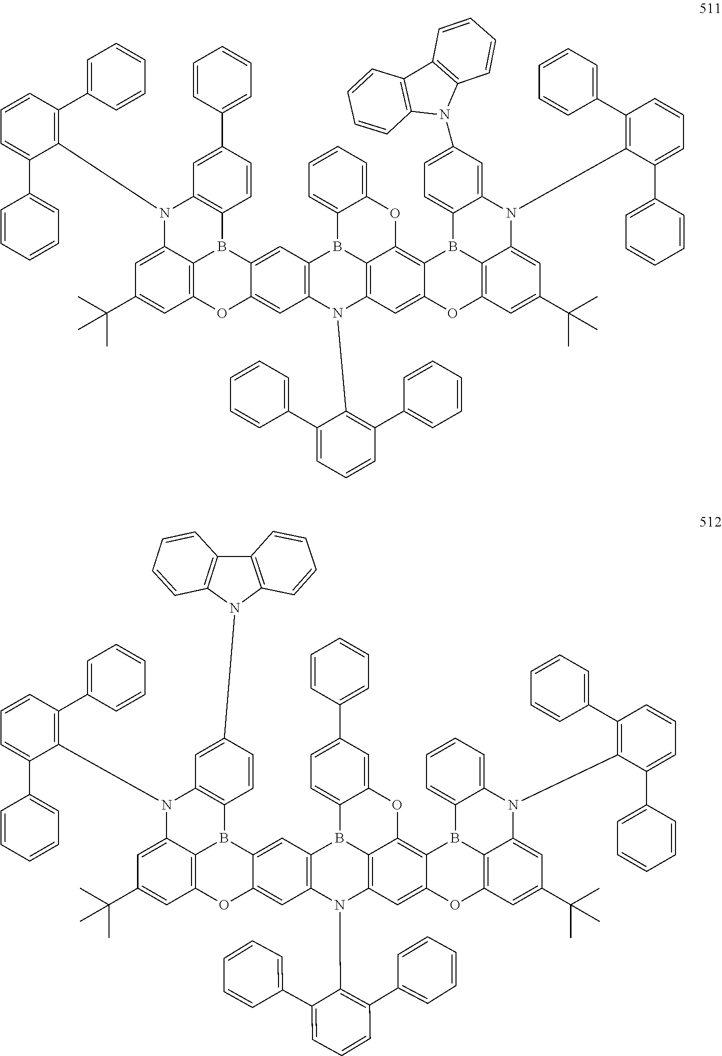 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccc(-n4c5ccccc5c5ccccc54)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)O2] 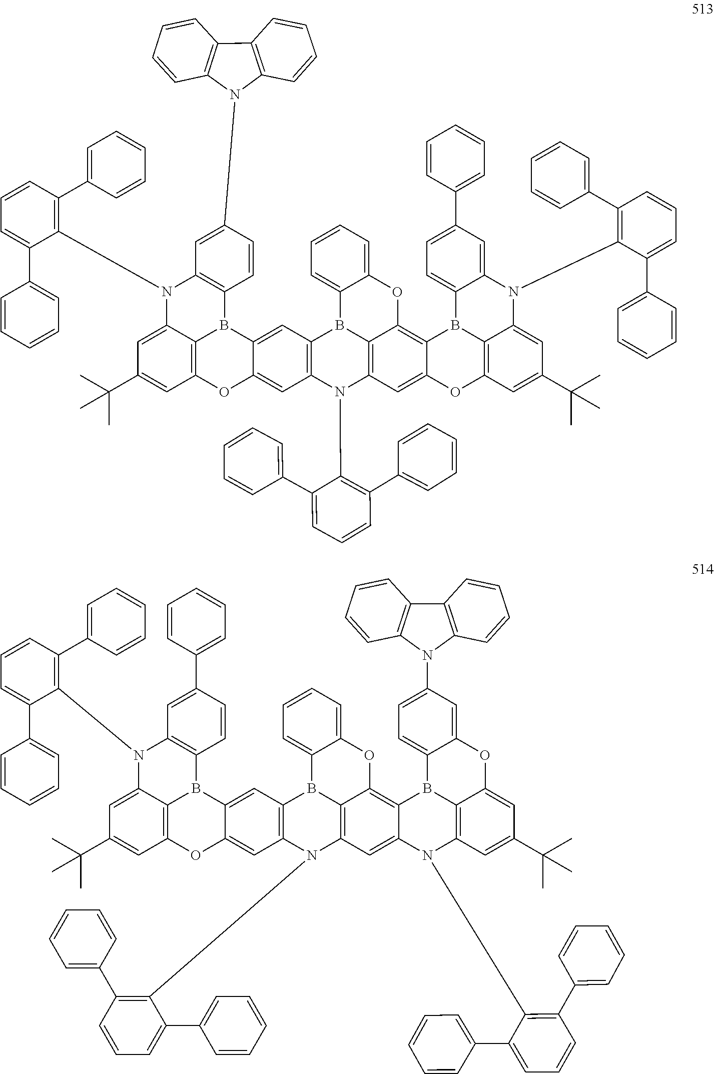 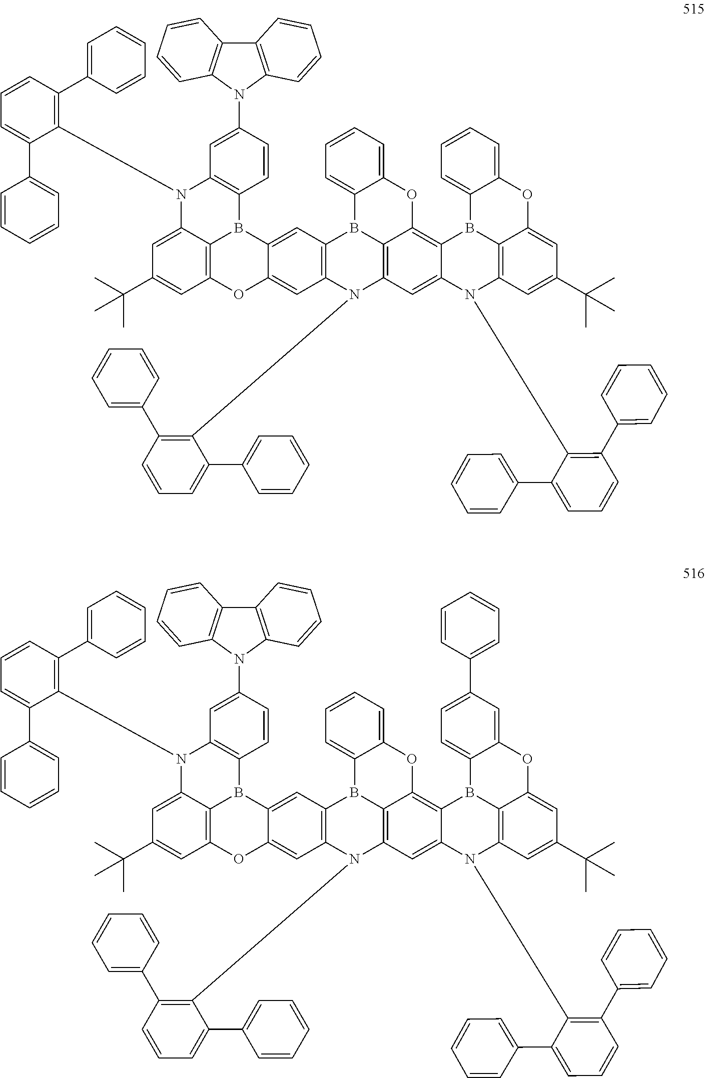 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccccc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3Oc3cc(C(C)(C)C)cc(c31)N2c1c(-c2ccccc2)cccc1-c1ccccc1] 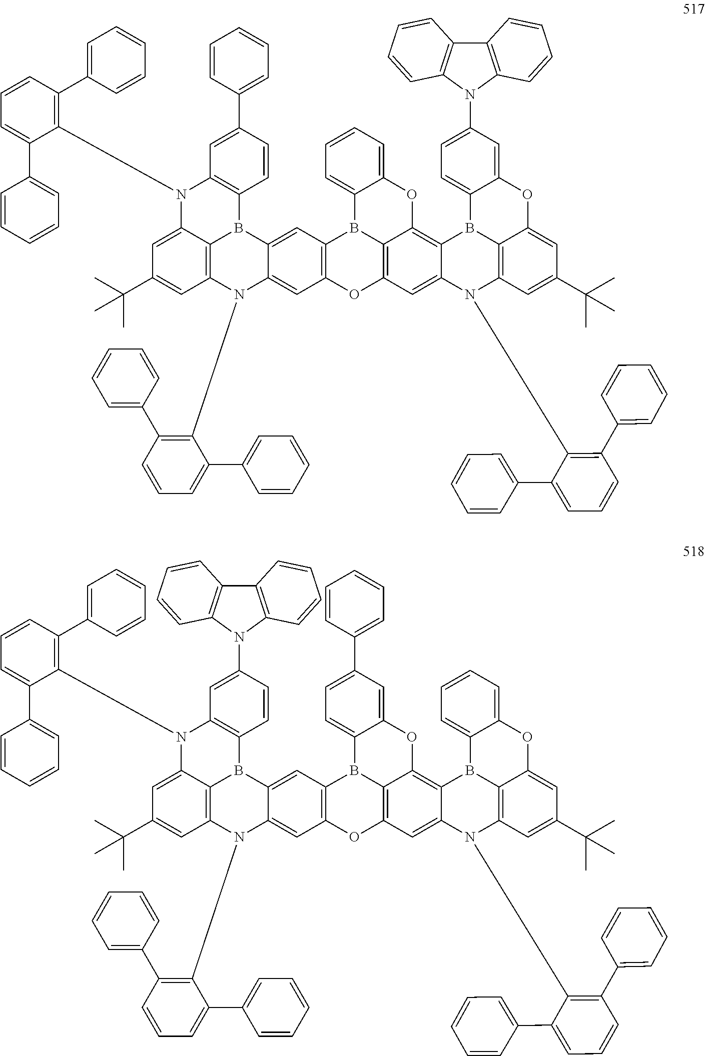 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1] 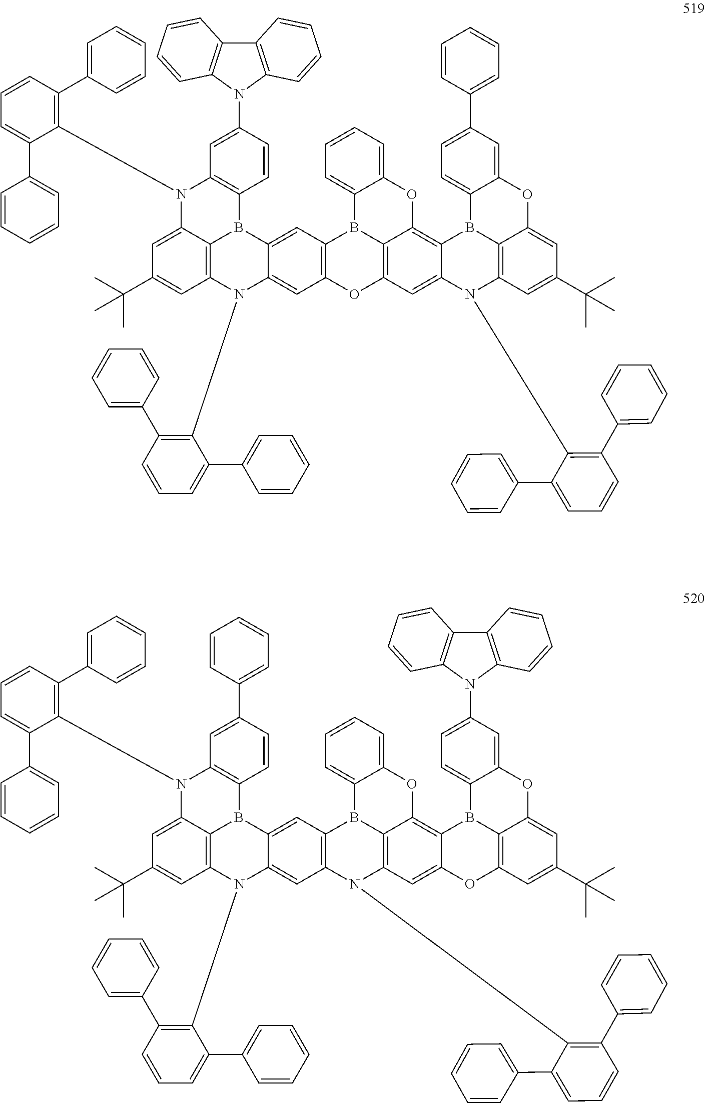 [SMILES: CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1O4)N(c1c(-c3ccccc3)cccc1-c1ccccc1)c1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1] 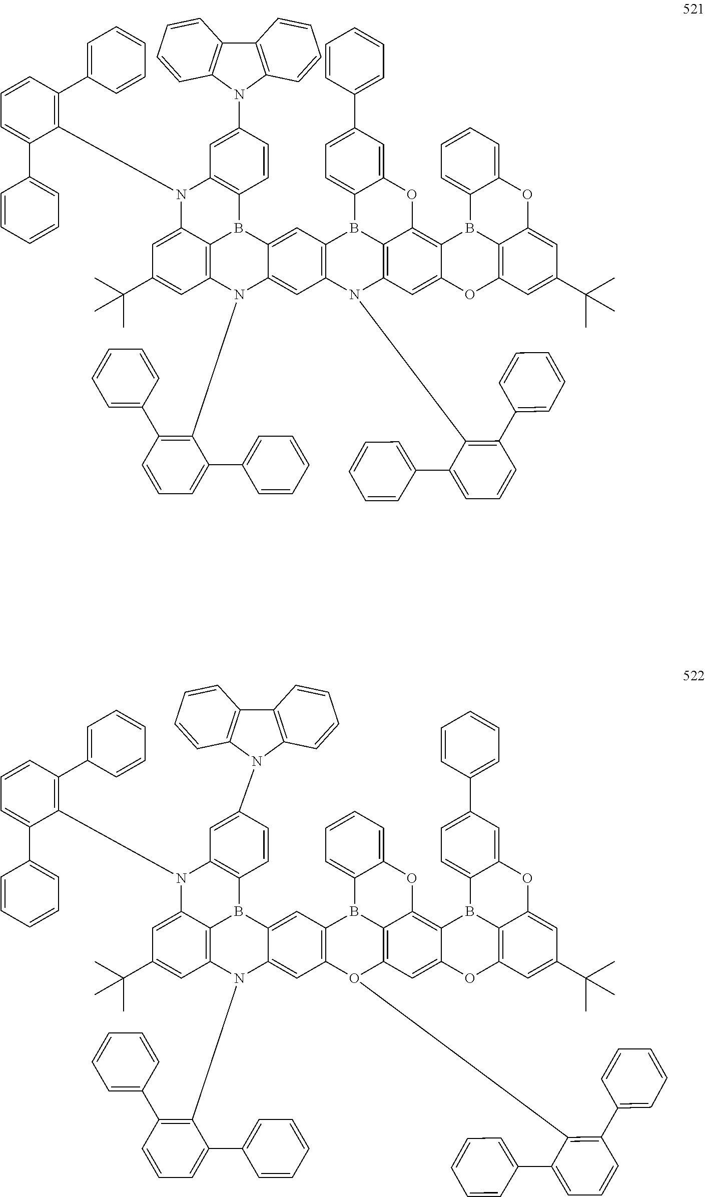 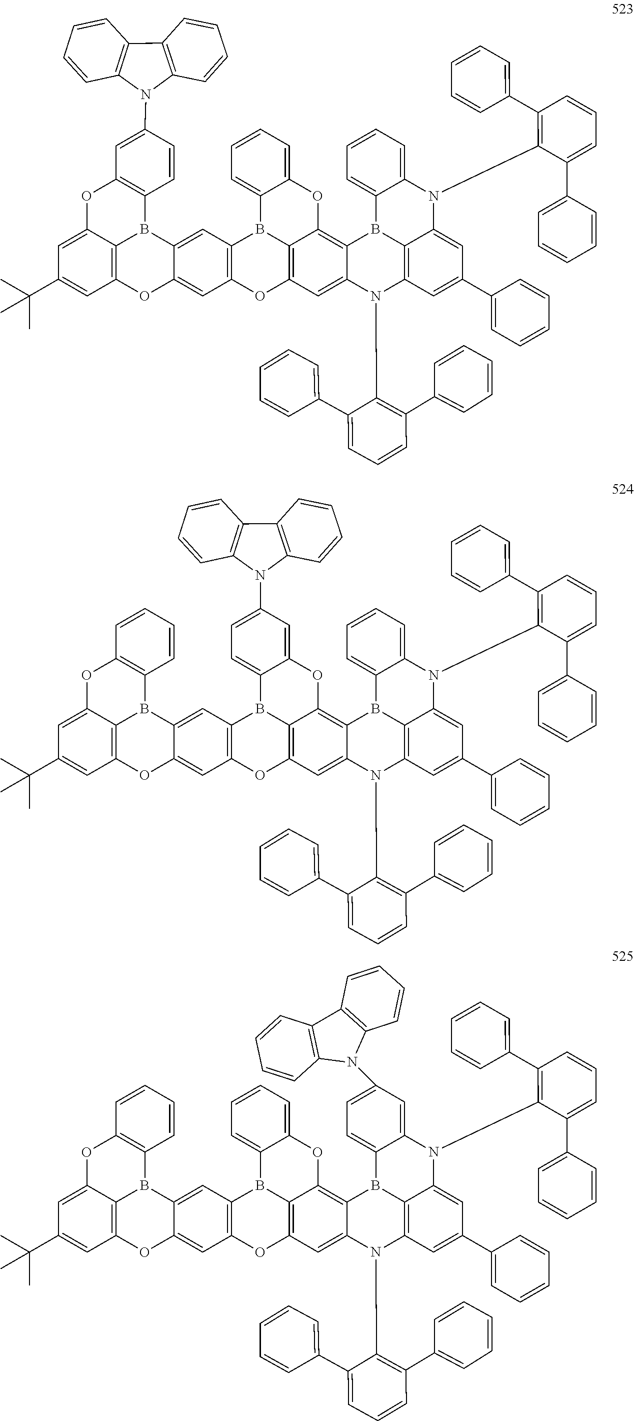 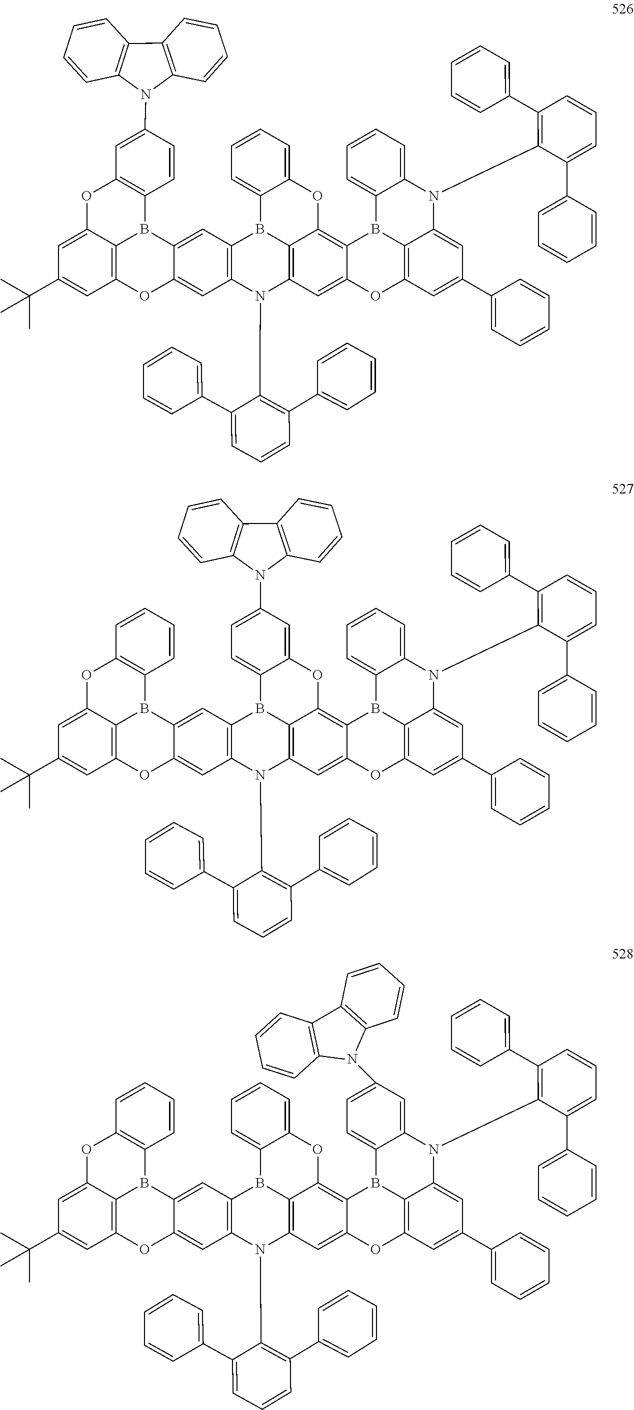 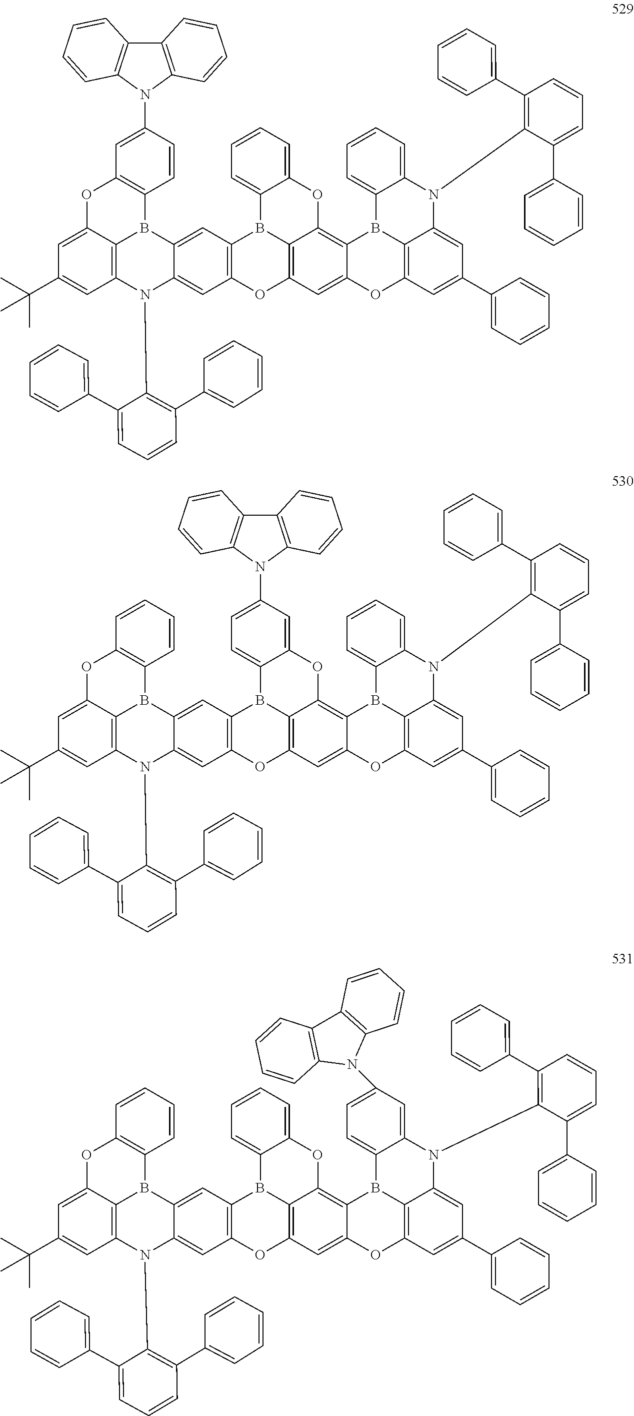 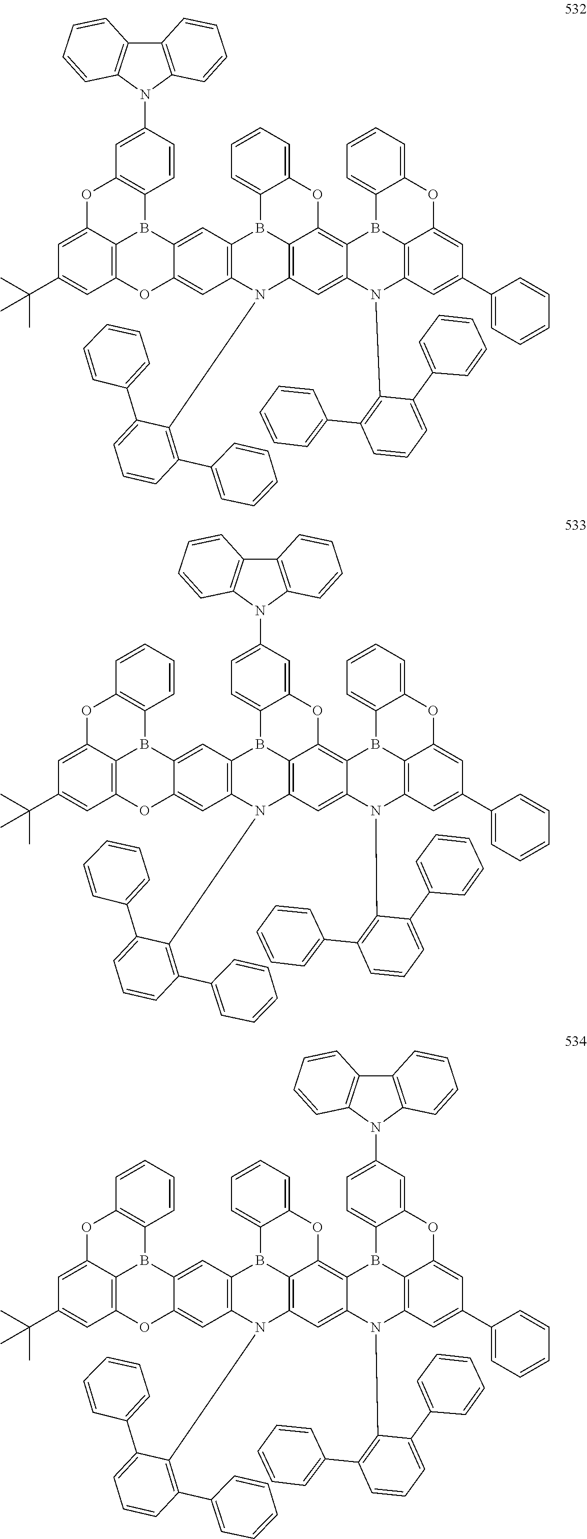 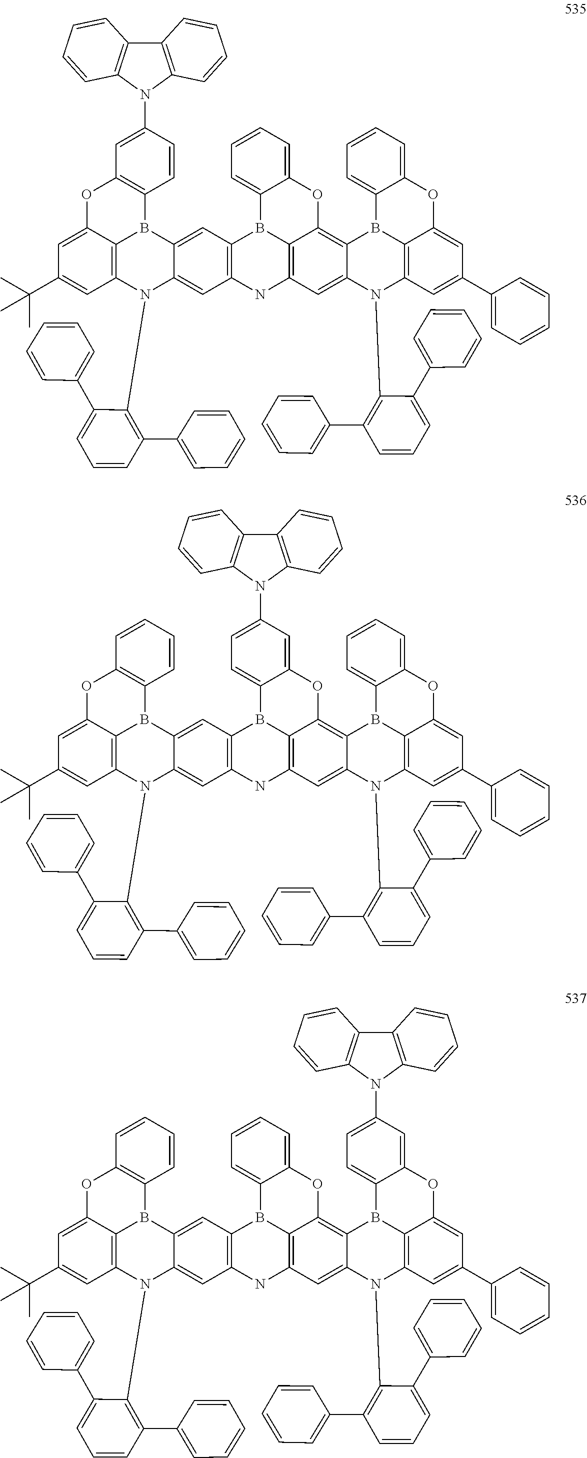 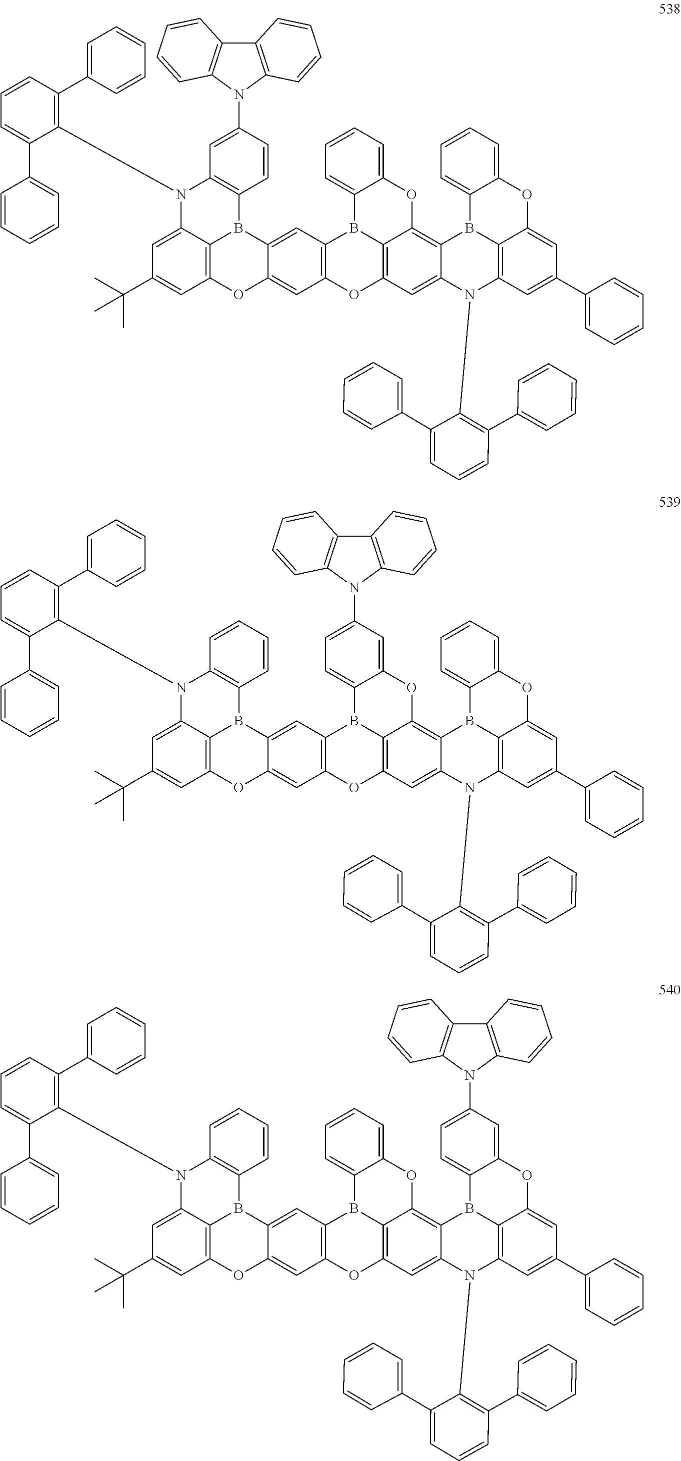 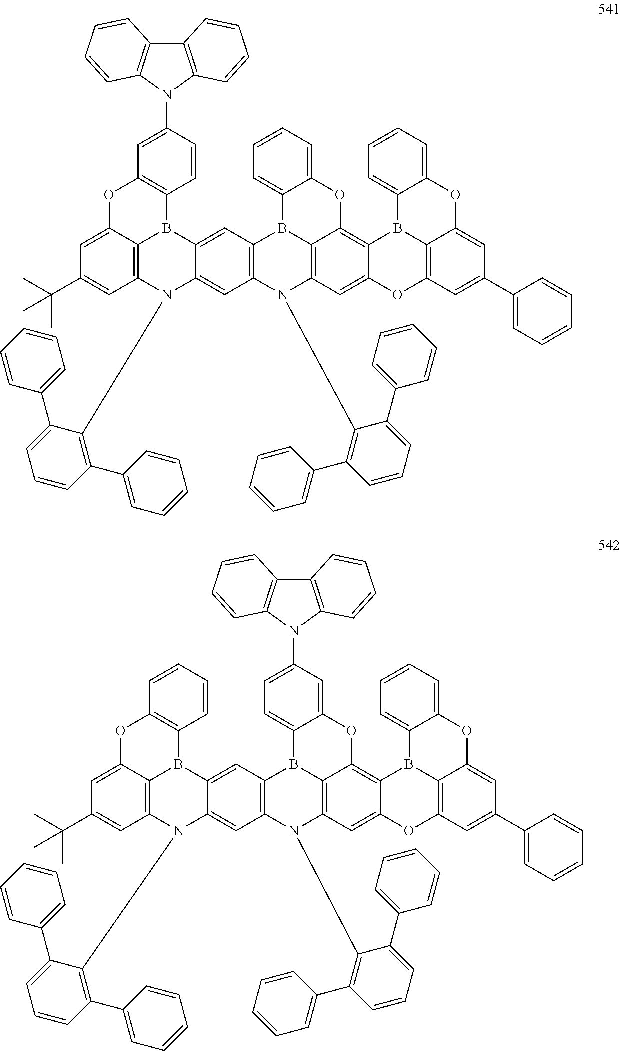 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1O2] 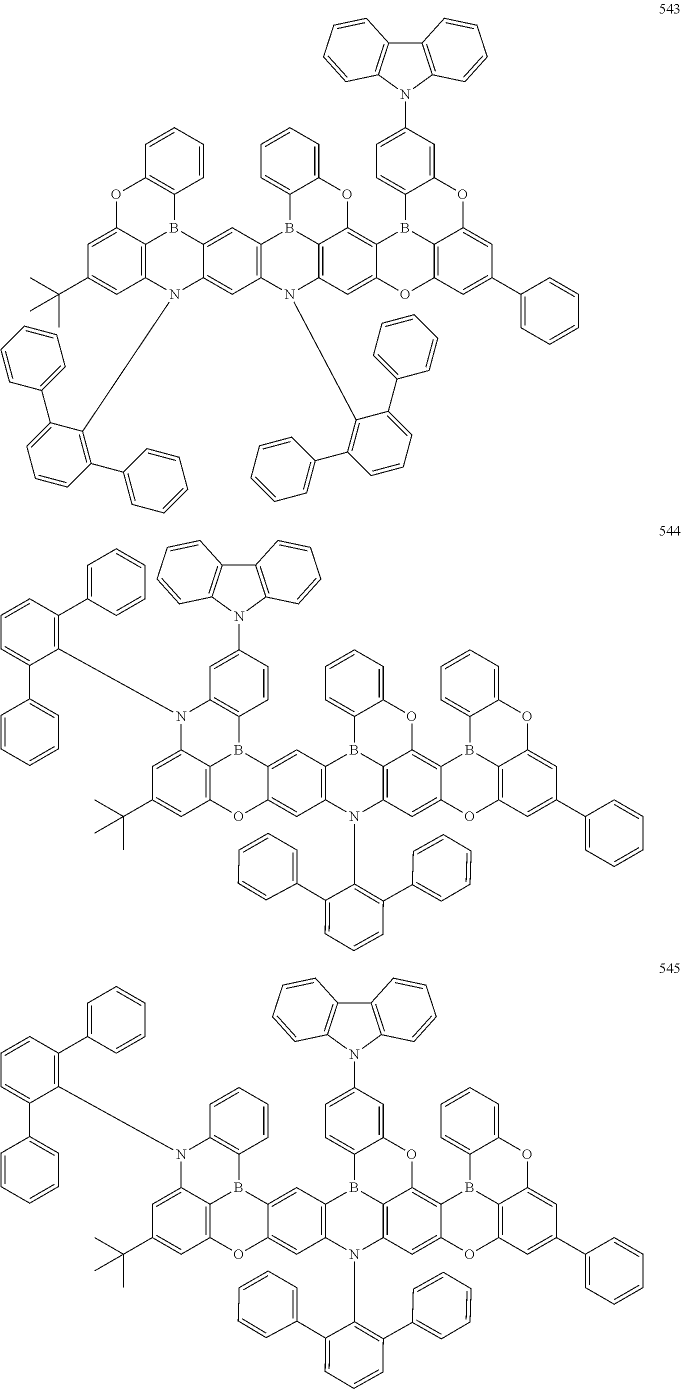 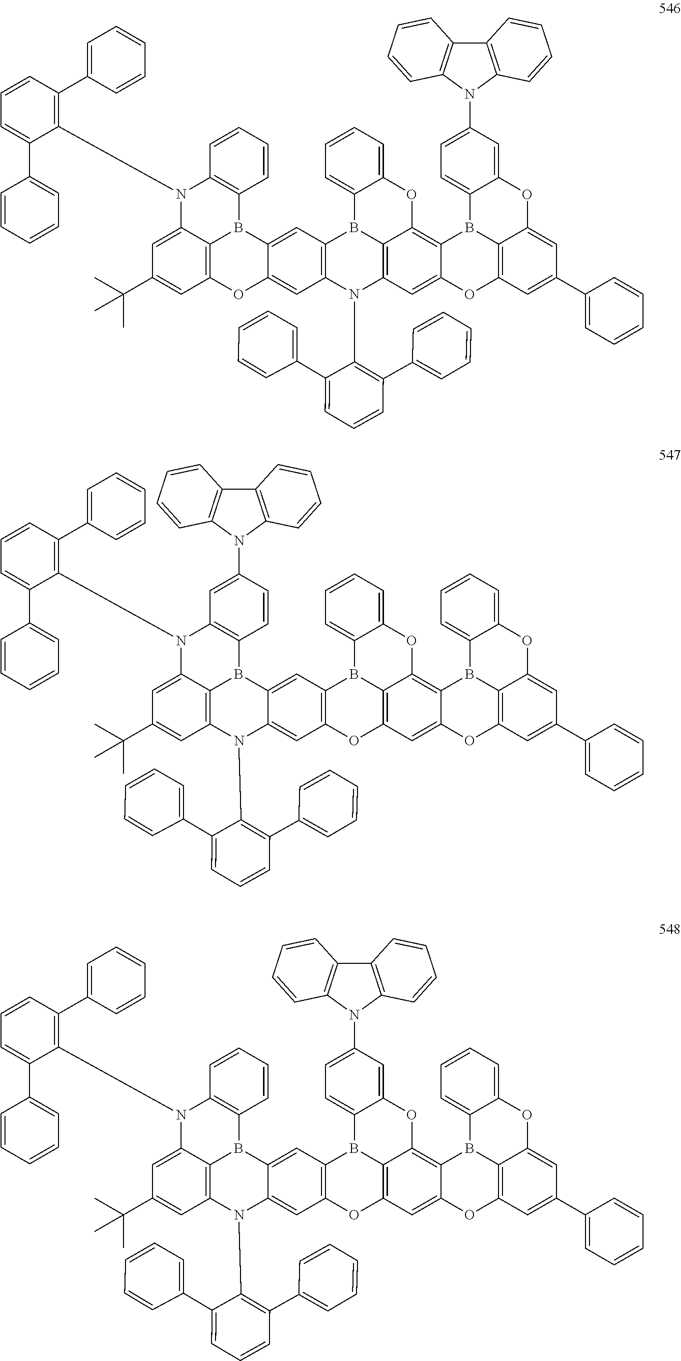 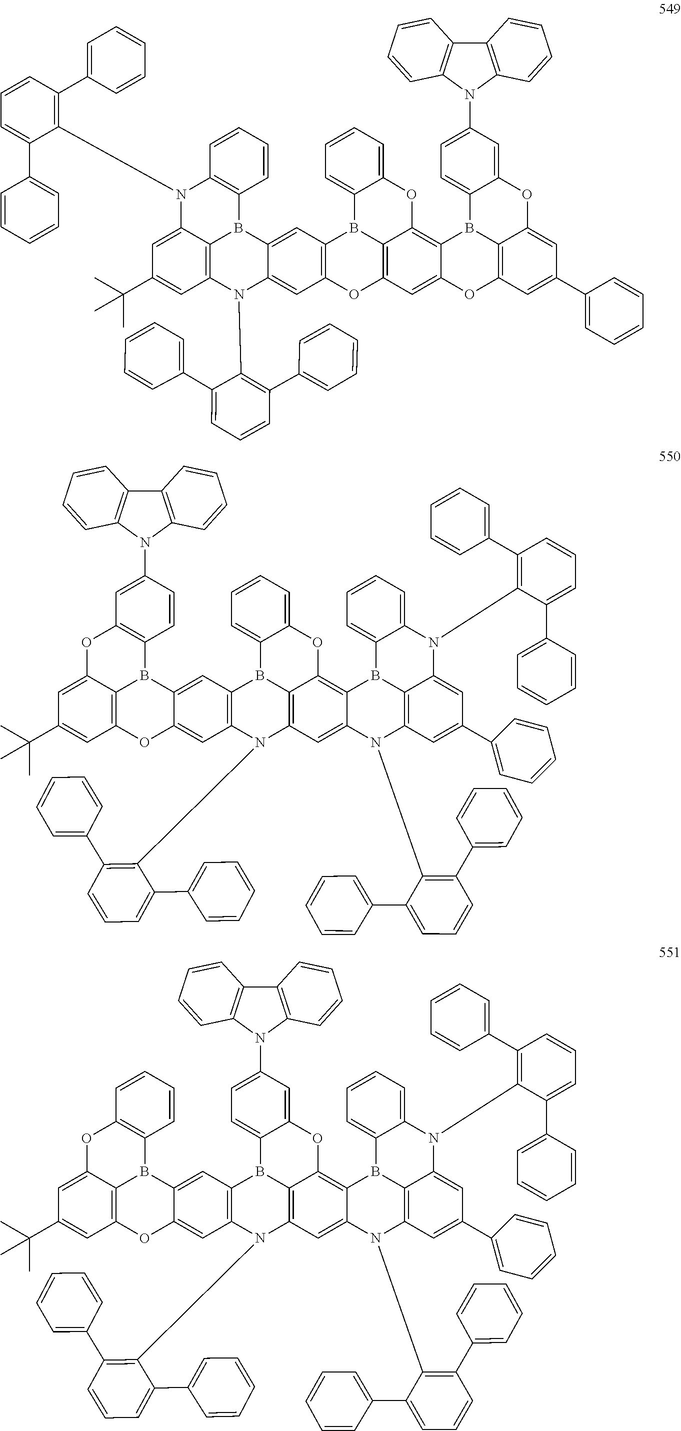 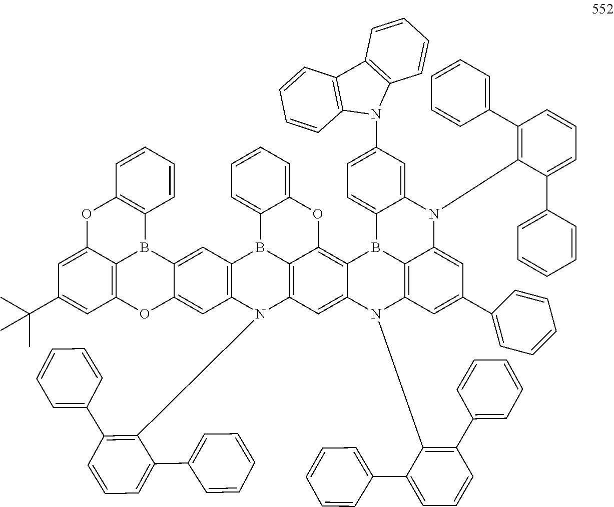 [SMILES: CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1] 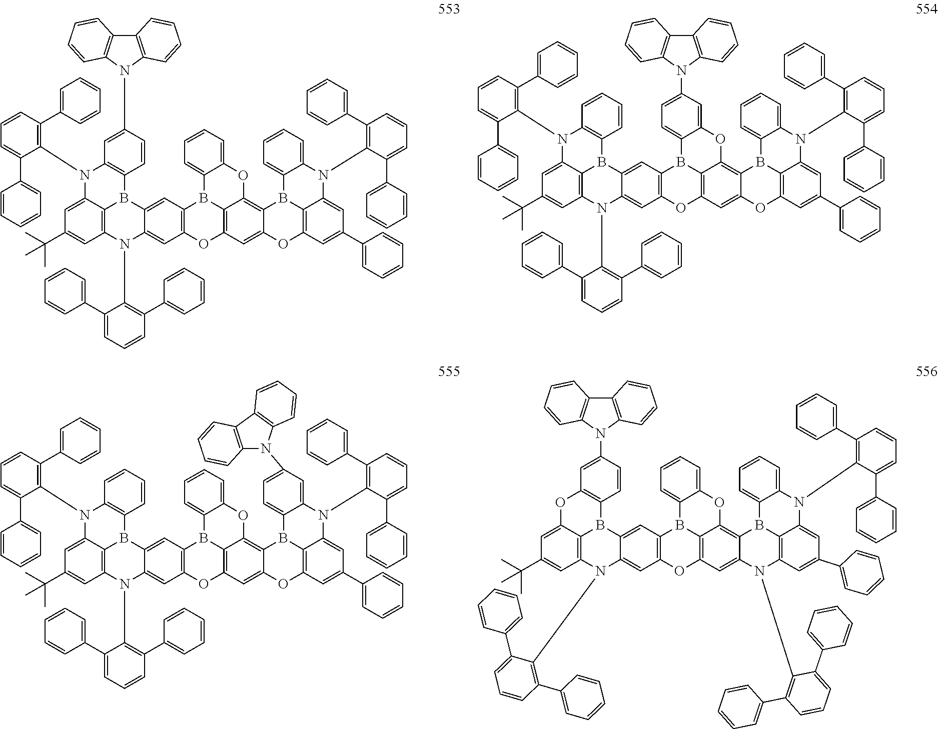 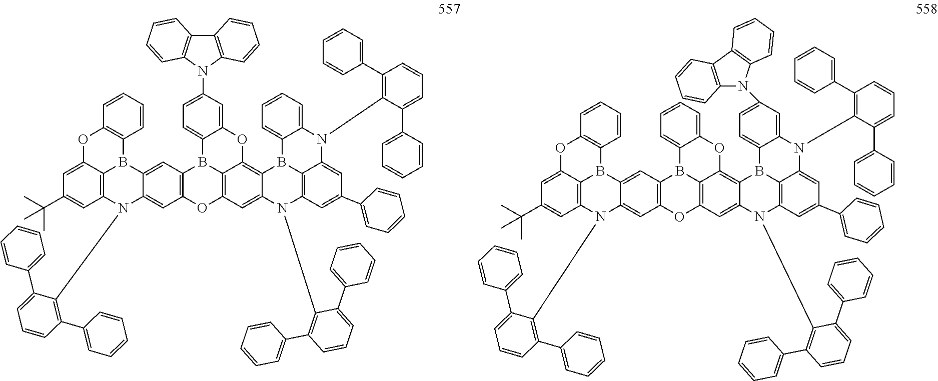 [SMILES: CC(C)(C)c1cc2c3c(c1)N(c1c(-c4ccccc4)cccc1-c1ccccc1)c1cc4c(cc1B3c1ccccc1O2)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)O4] 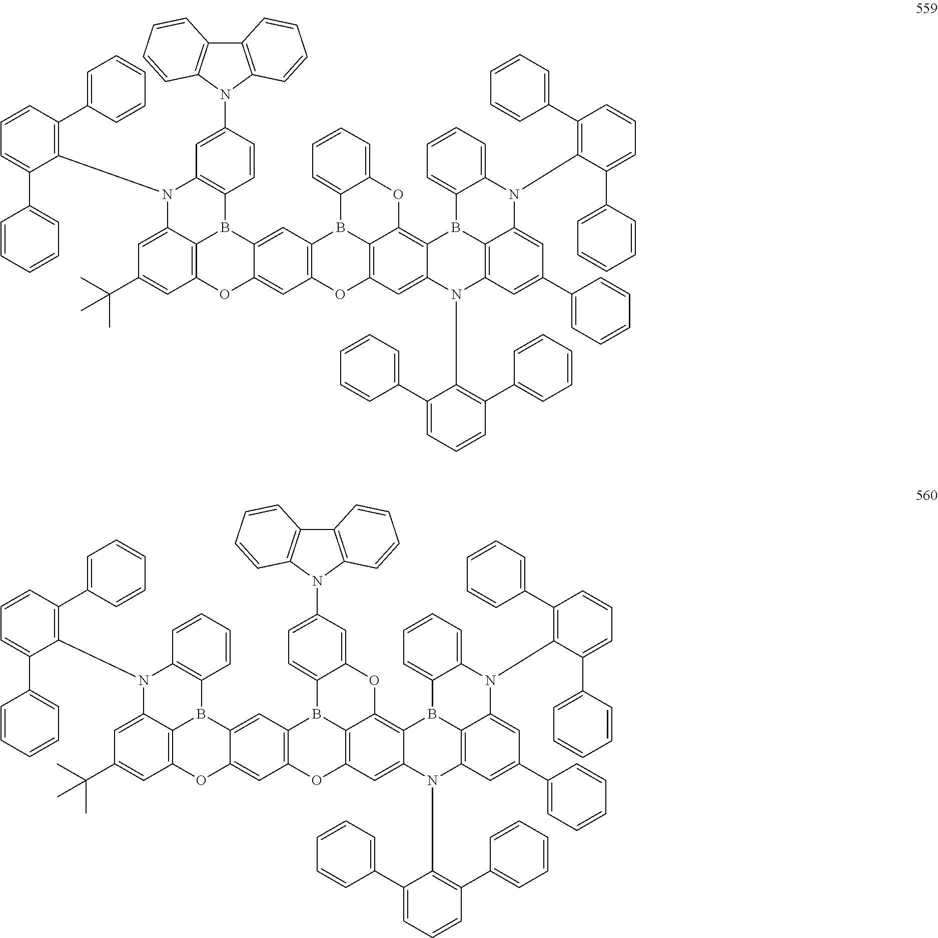 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccccc3N(c3c(-c4ccccc4)cccc3-c3ccccc3)c3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-n3c5ccccc5c5ccccc53)cc1O4)B1c3ccccc3N(c3c(-c4ccccc4)cccc3-c3ccccc3)c3cc(-c4ccccc4)cc(c31)N2c1c(-c2ccccc2)cccc1-c1ccccc1] 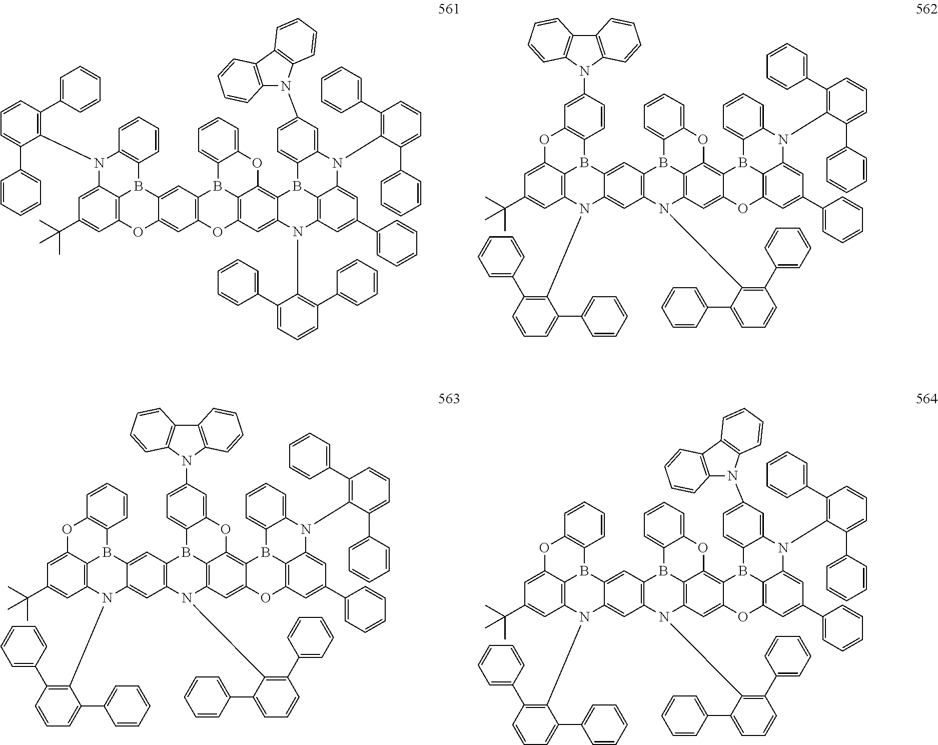 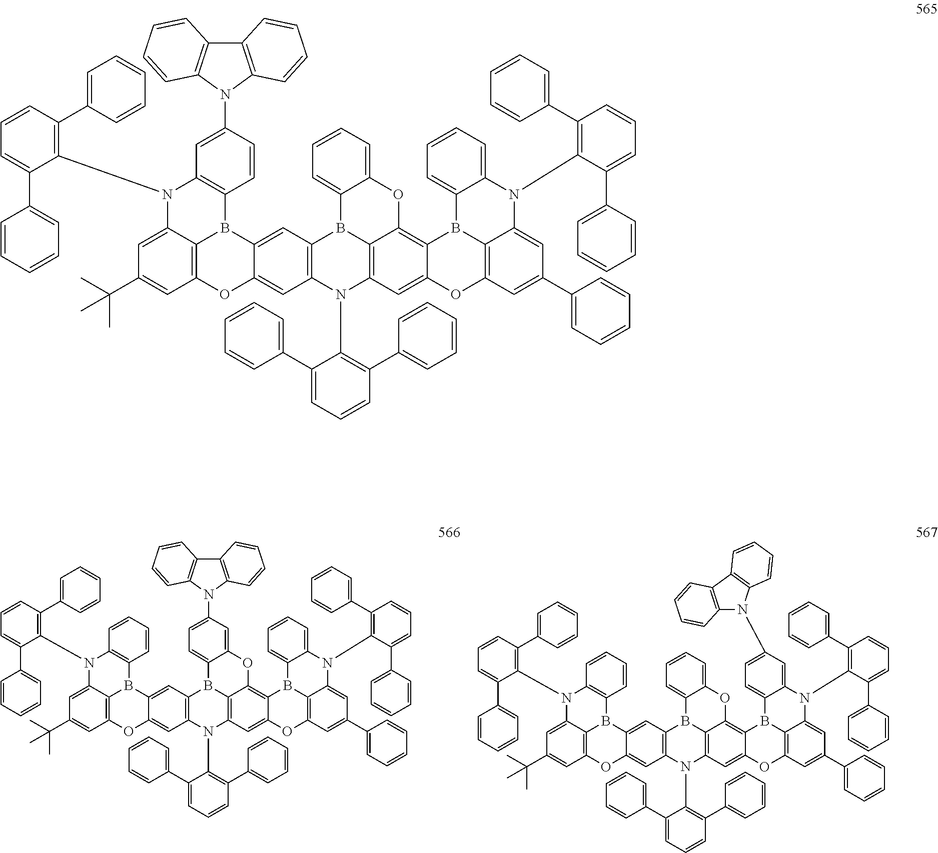 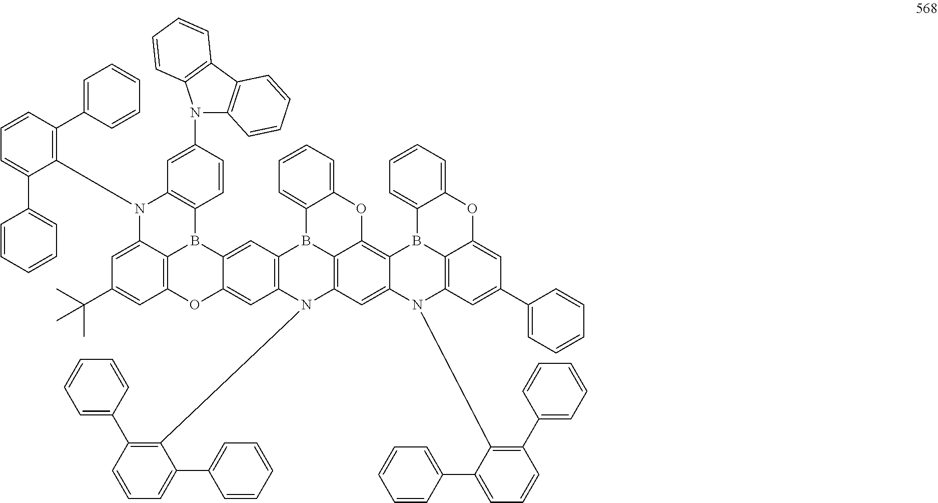 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccccc3Oc3cc(-c4ccccc4)cc(c31)N2c1c(-c2ccccc2)cccc1-c1ccccc1] 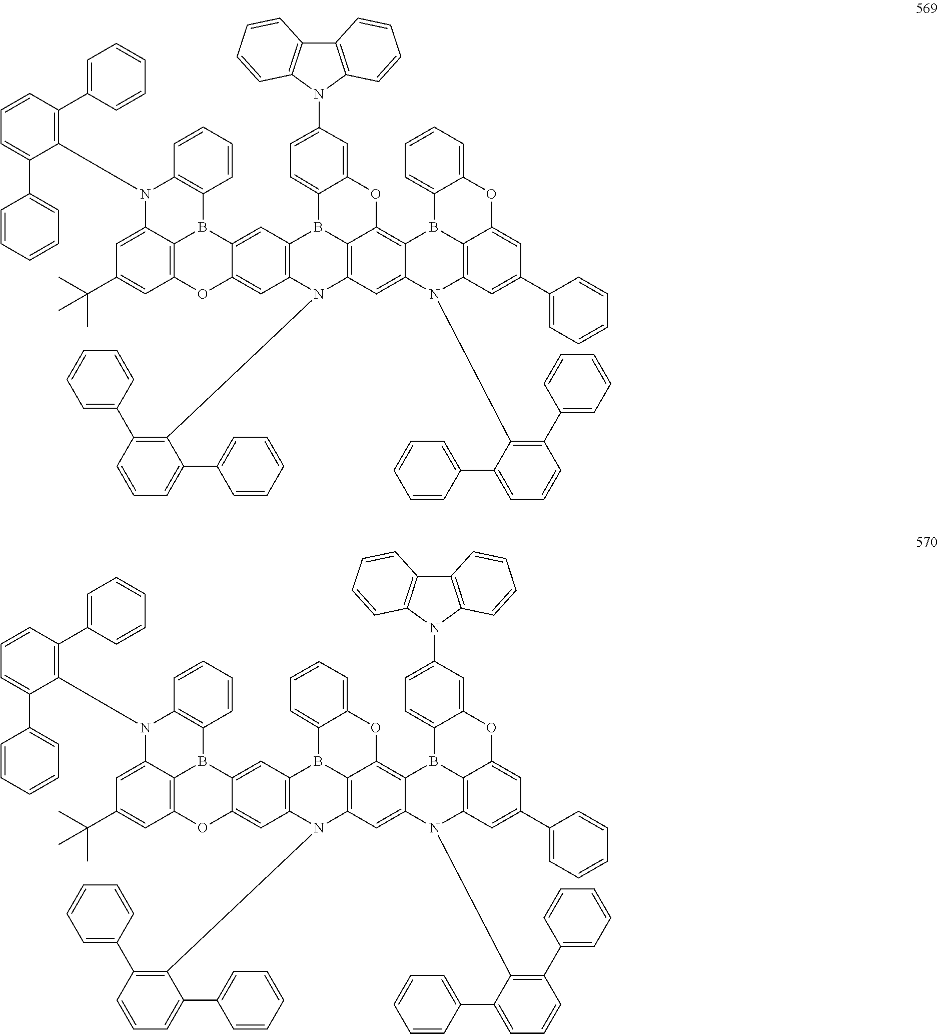 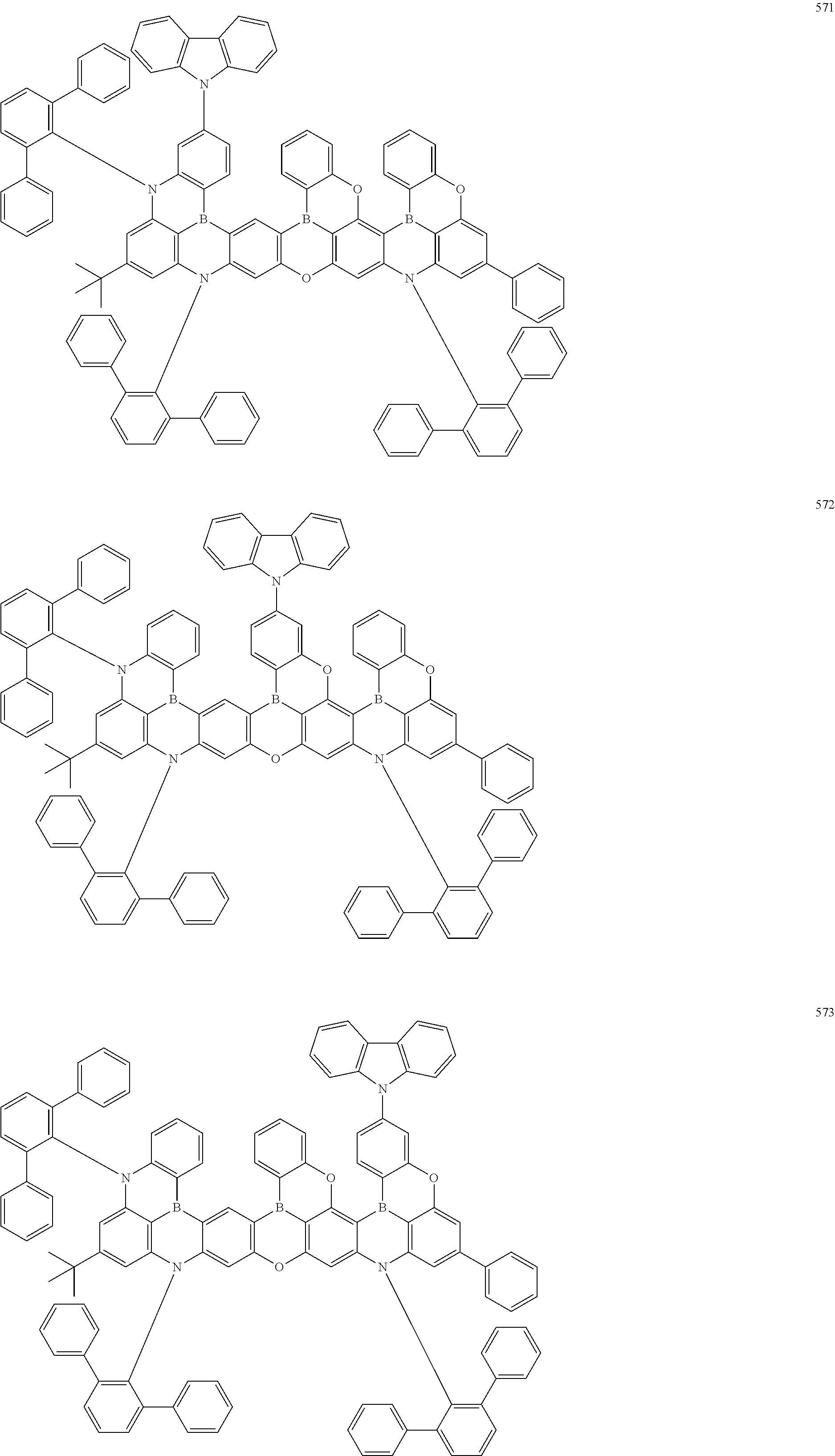 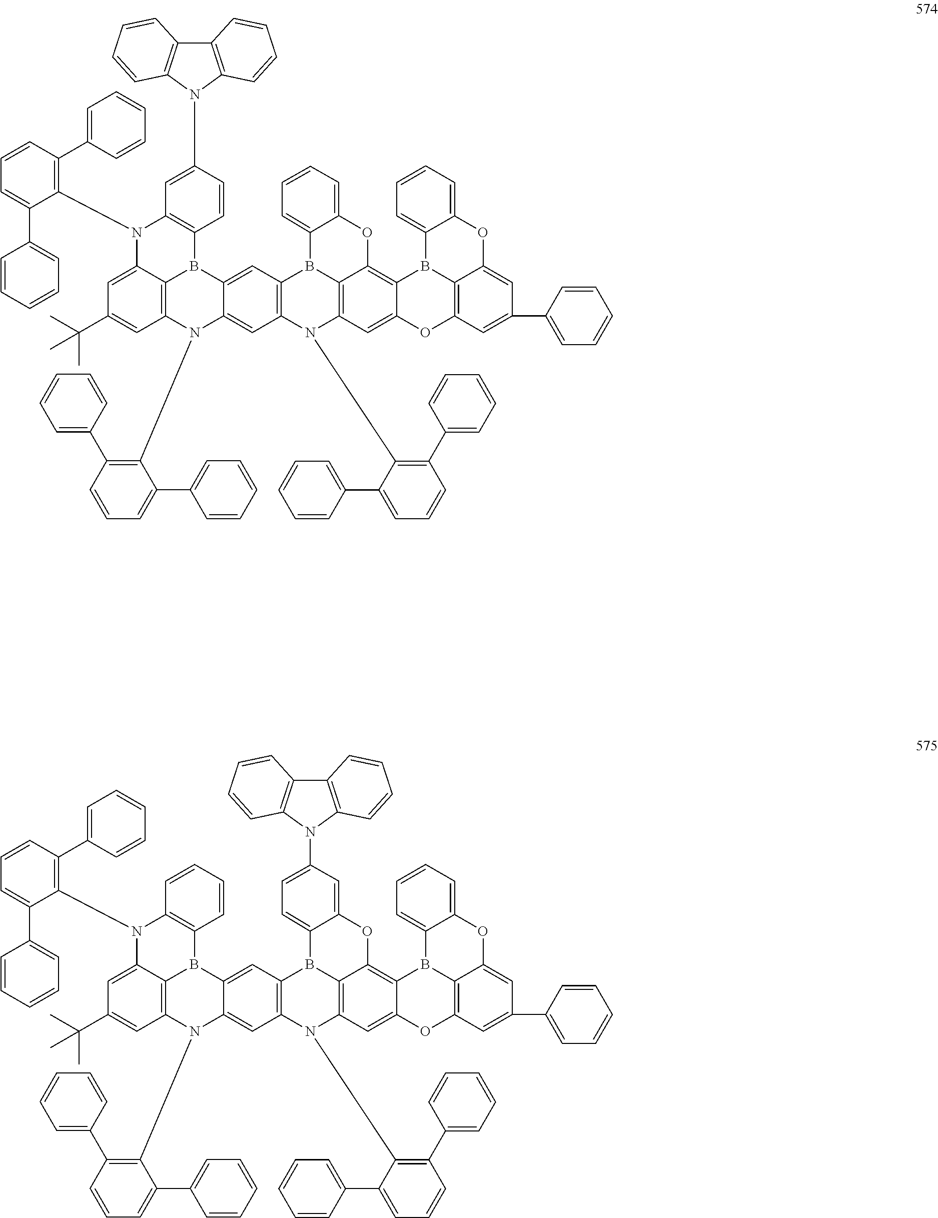 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-n3c5ccccc5c5ccccc53)cc2Oc2c3c(cc(c21)N4c1c(-c2ccccc2)cccc1-c1ccccc1)Oc1cc(-c2ccccc2)cc2c1B3c1ccccc1O2] 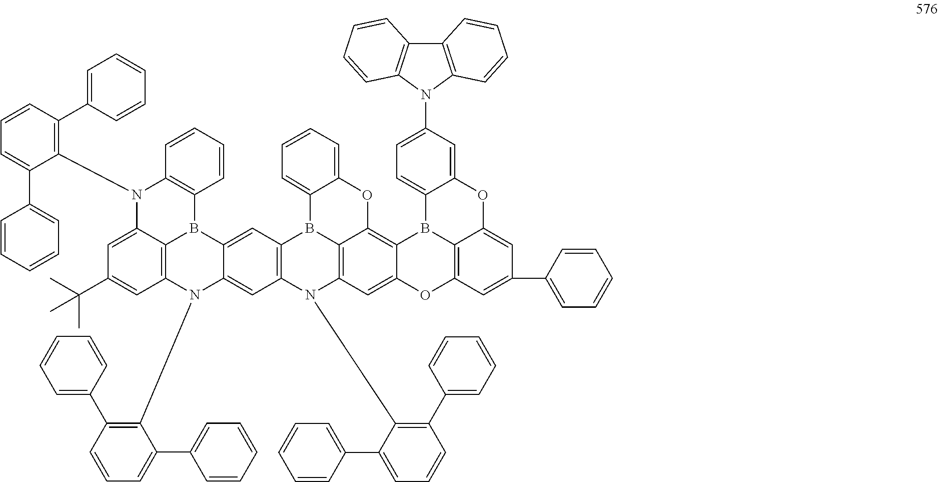 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1O2] 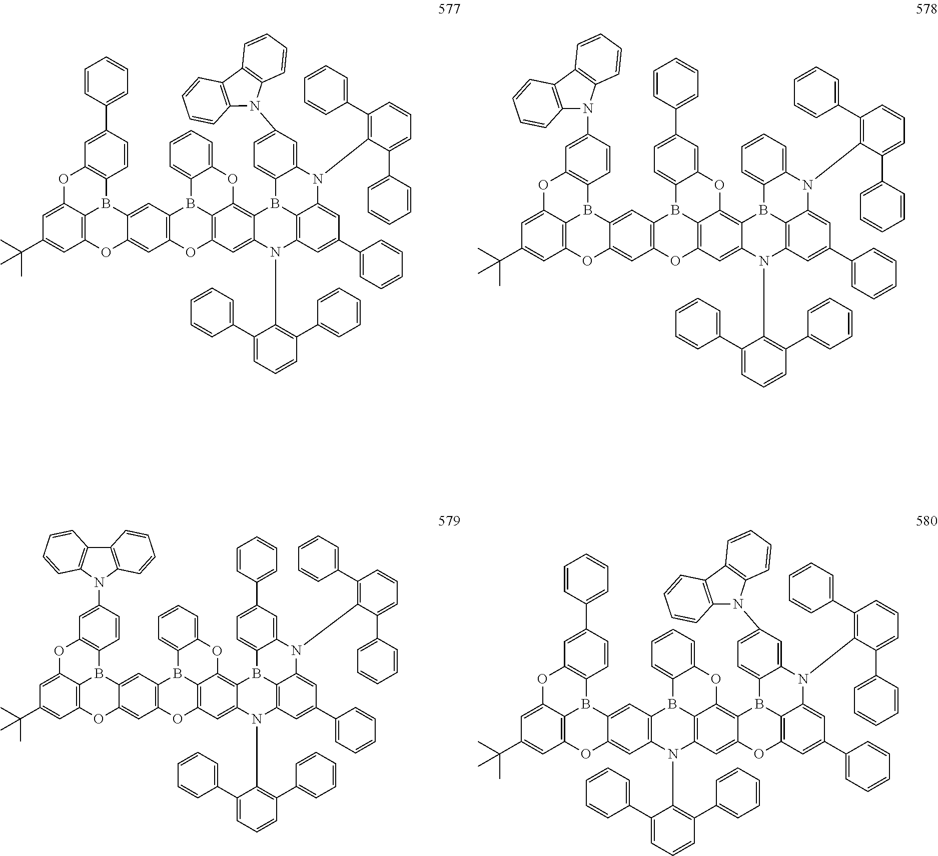 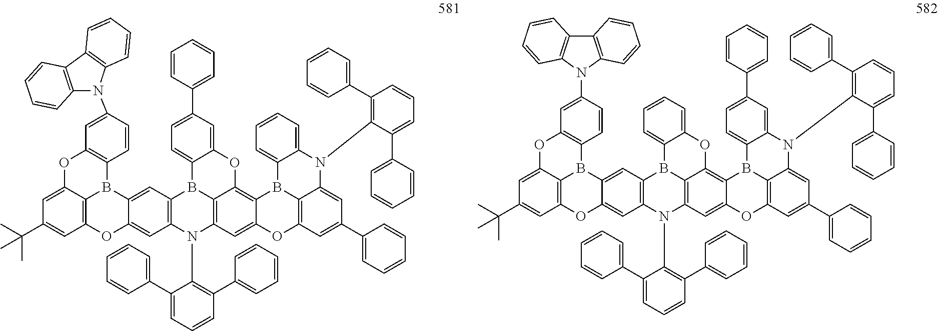 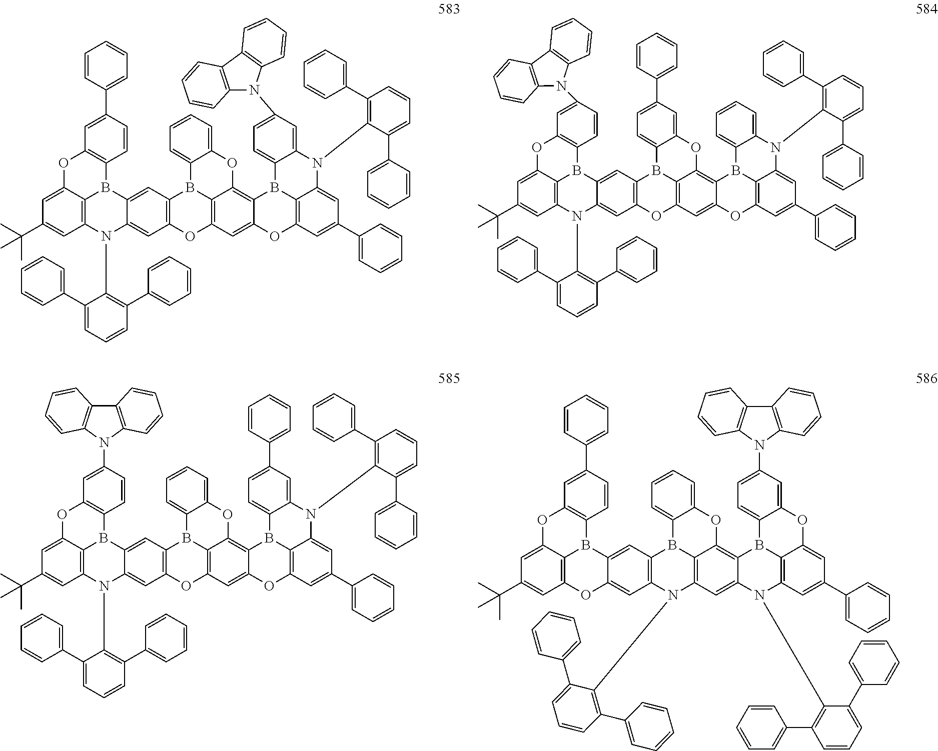 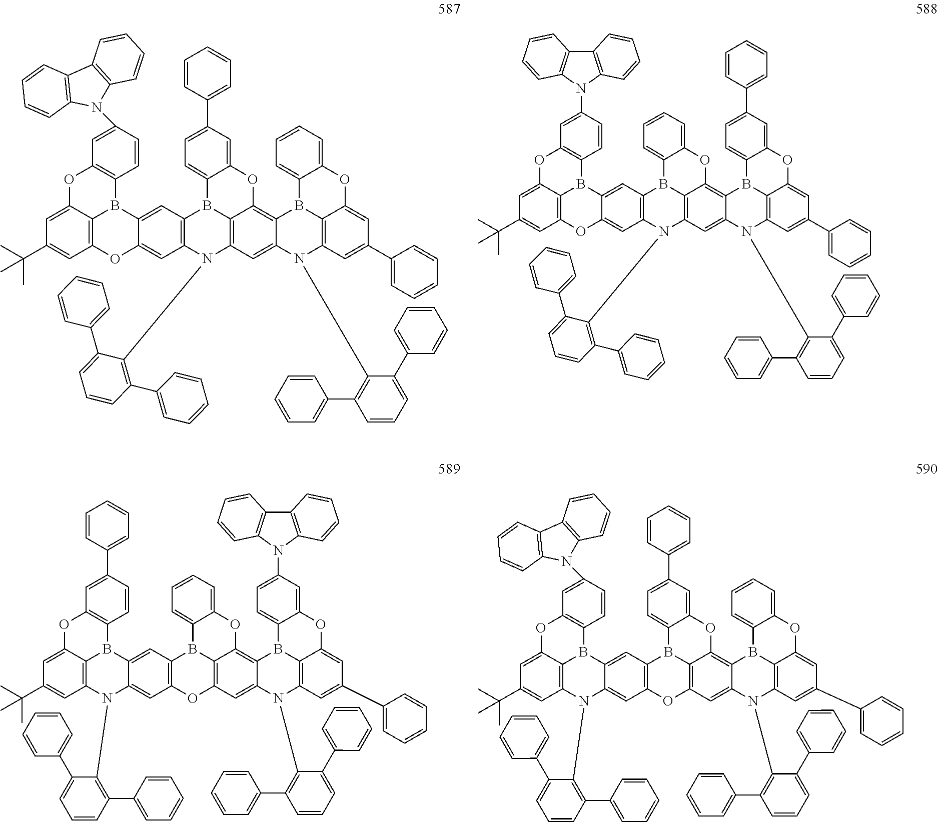 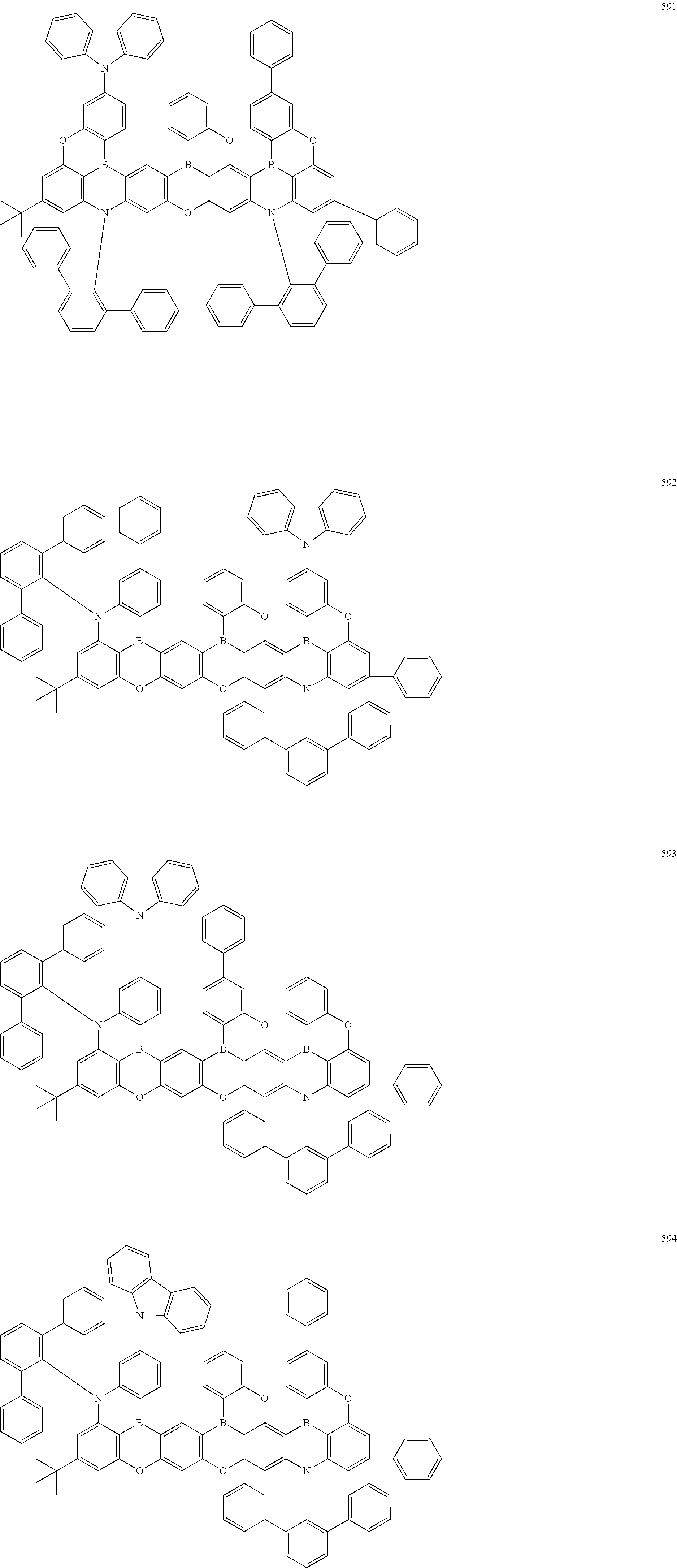 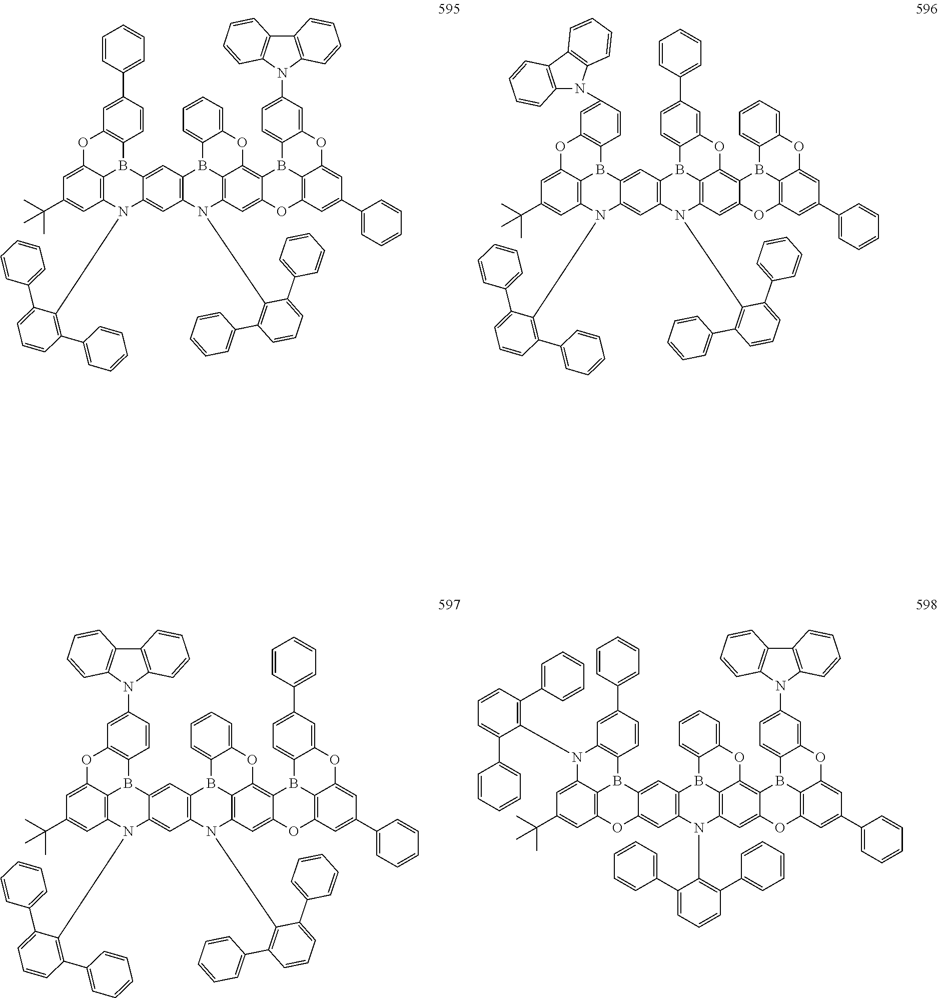 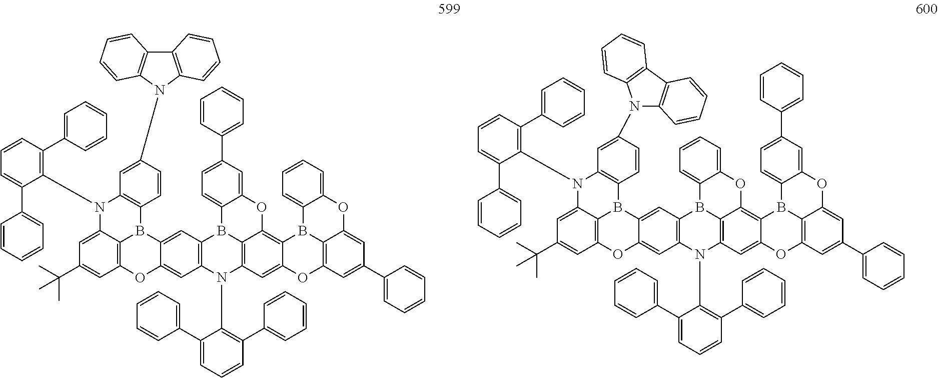 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccccc3Oc3cc(-c4ccccc4)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccccc1O4)B1c3ccc(-c4ccccc4)cc3Oc3cc(-c4ccccc4)cc(c31)O2] 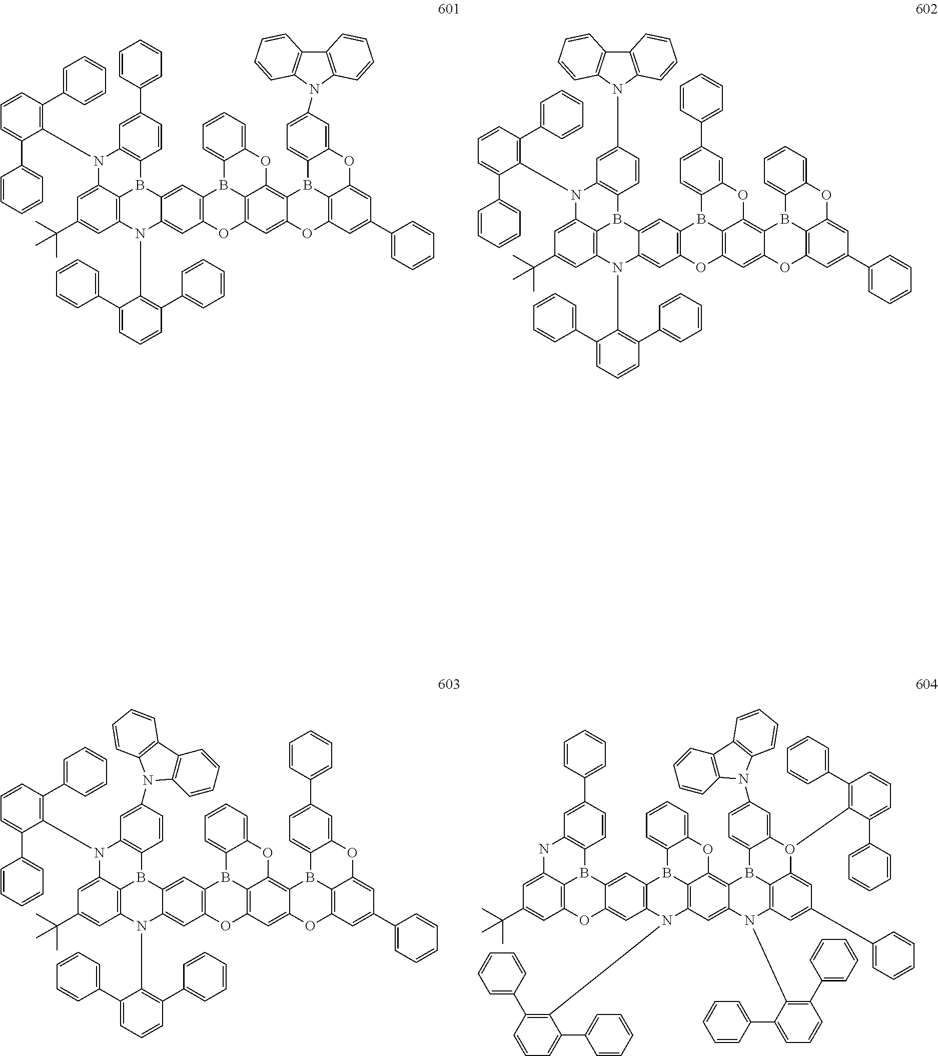 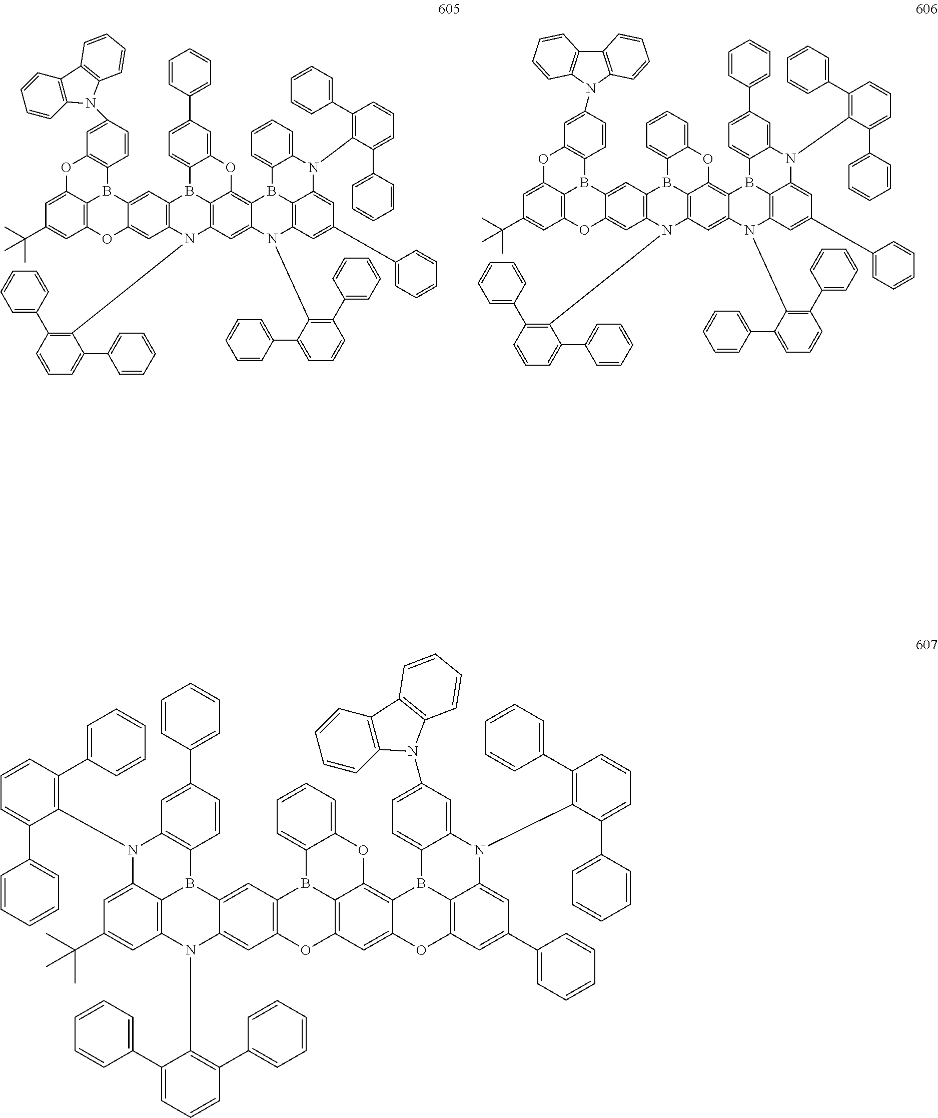 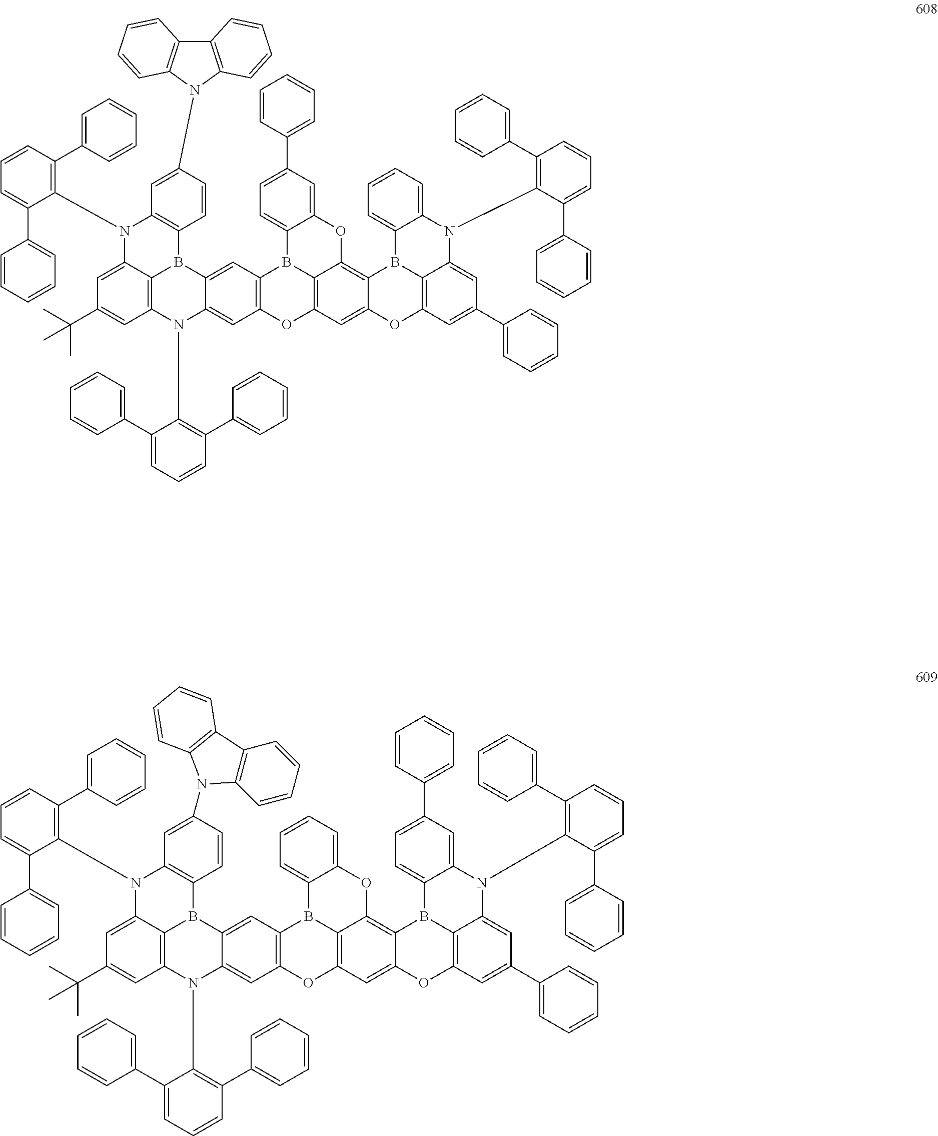 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)O1)O4] 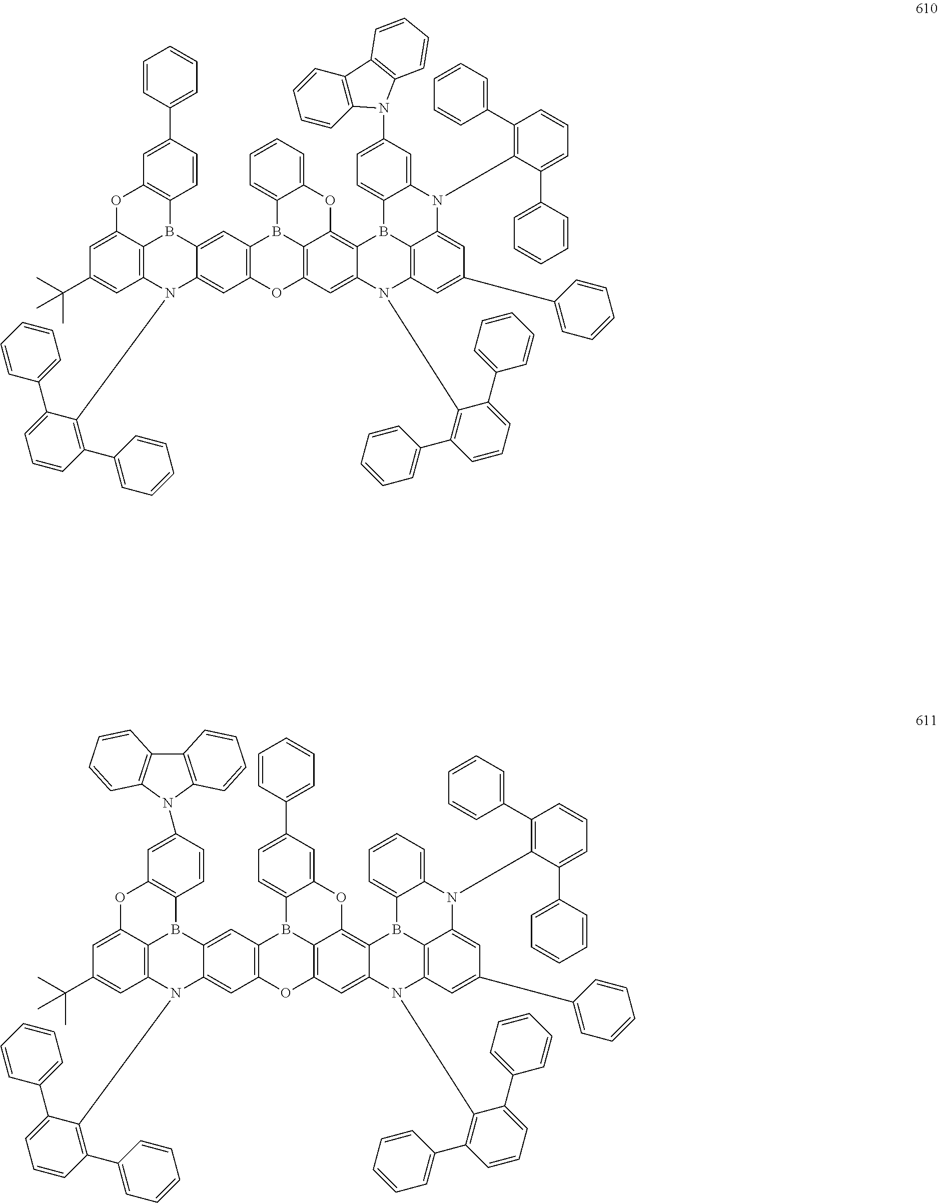 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4] 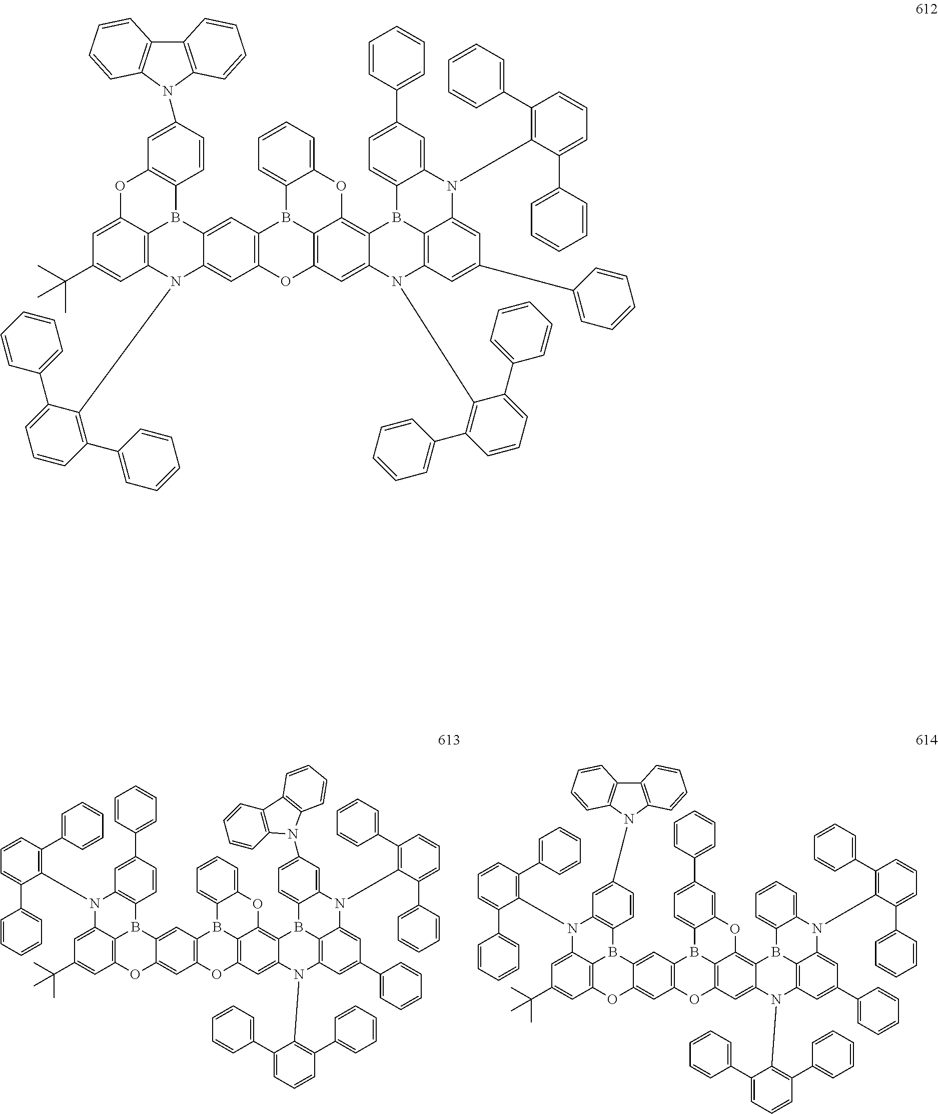 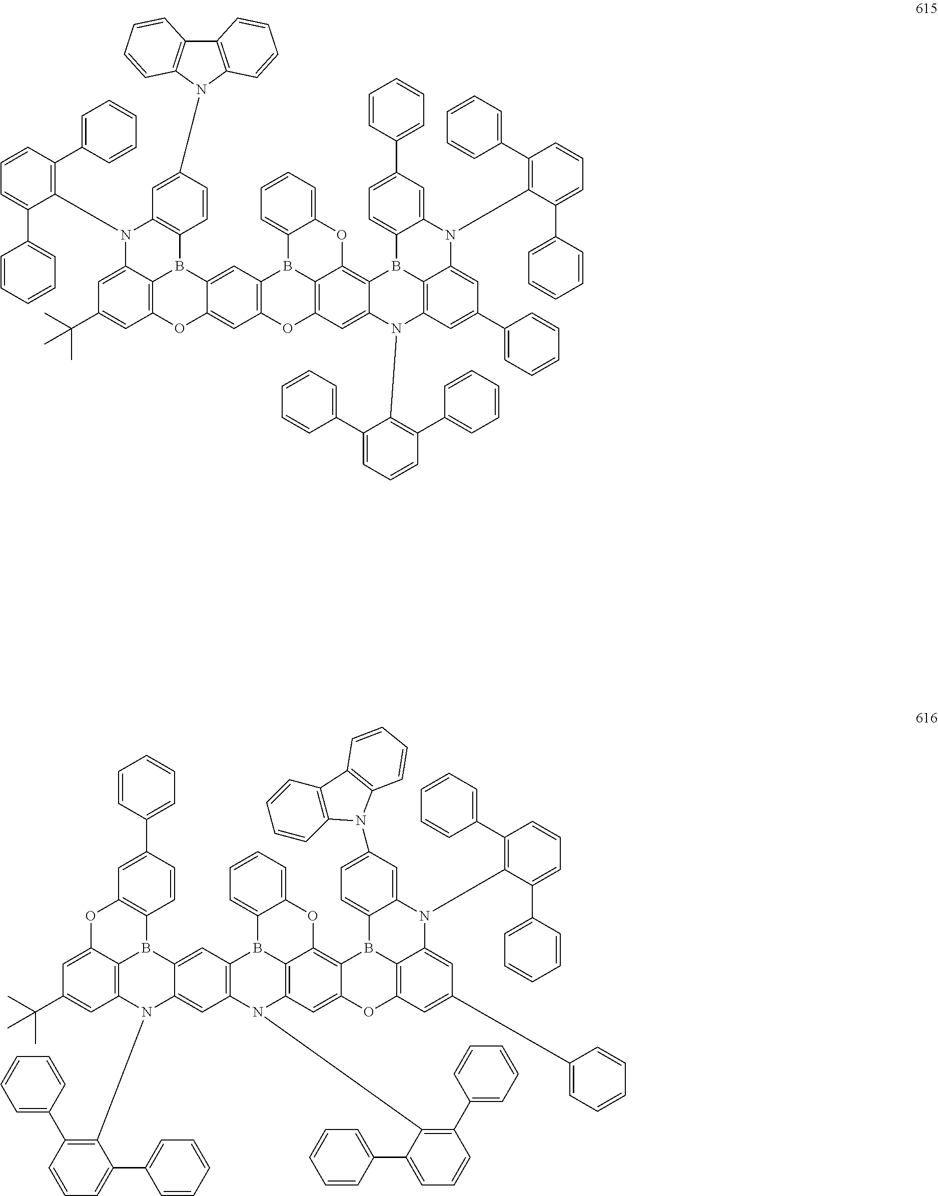 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(-c2ccccc2)cc2c1B3c1ccc(-n3c4ccccc4c4ccccc43)cc1N2c1c(-c2ccccc2)cccc1-c1ccccc1] 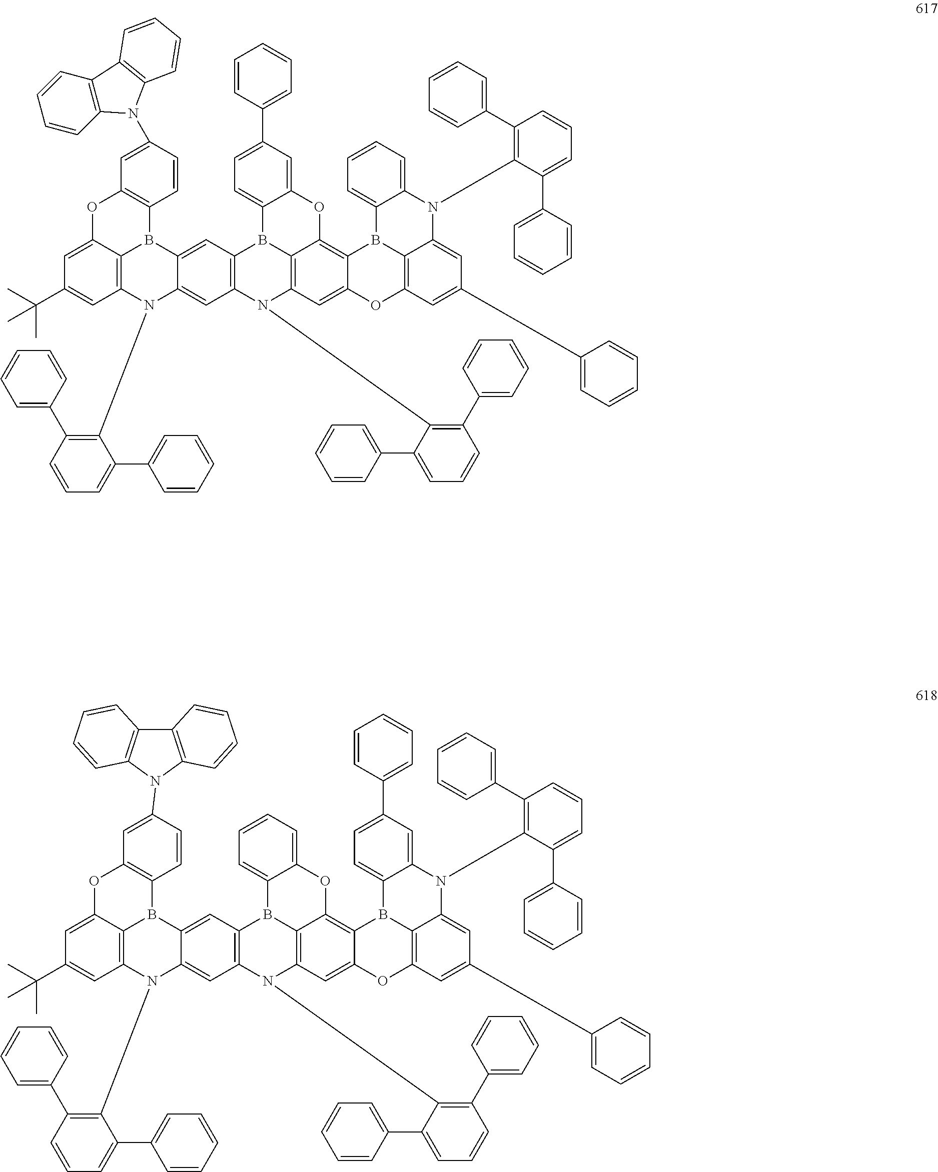 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c3c(cc(c21)N4c1c(-c2ccccc2)cccc1-c1ccccc1)Oc1cc(-c2ccccc2)cc2c1B3c1ccc(-c3ccccc3)cc1N2c1c(-c2ccccc2)cccc1-c1ccccc1] 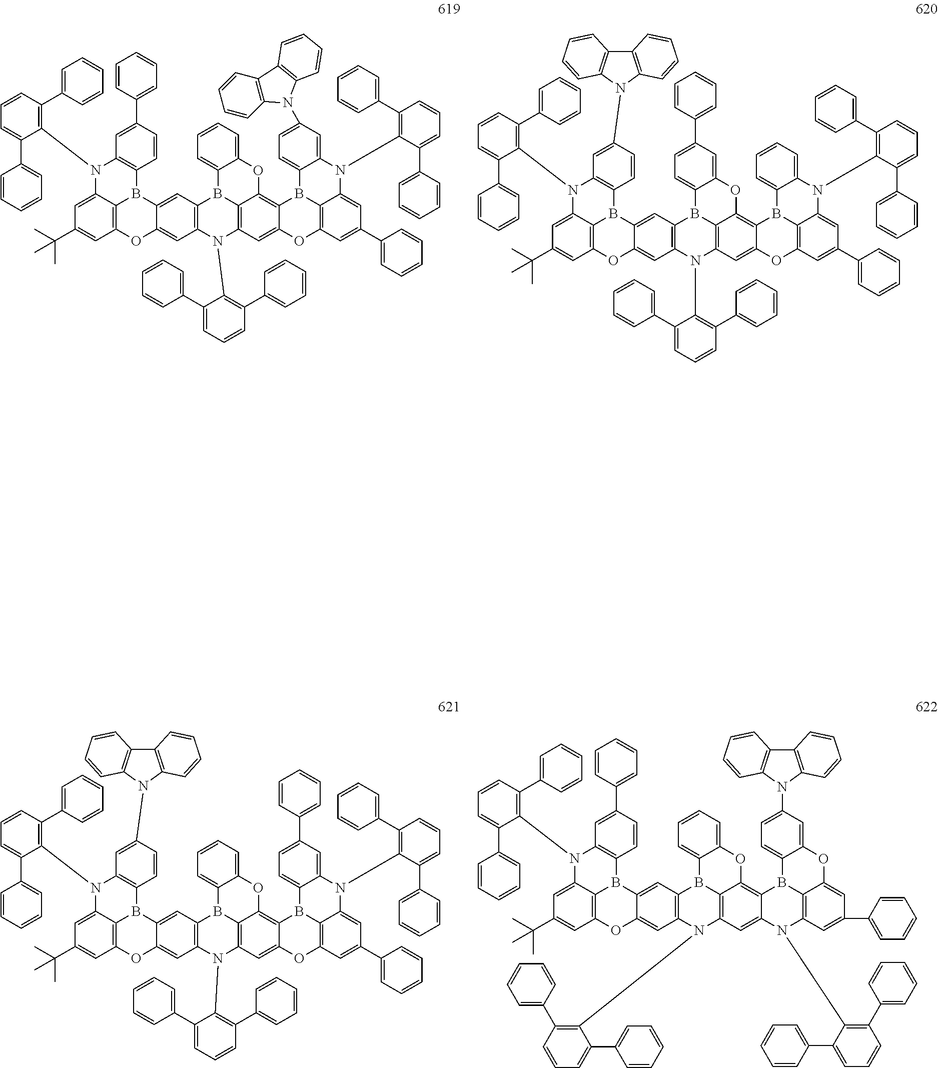 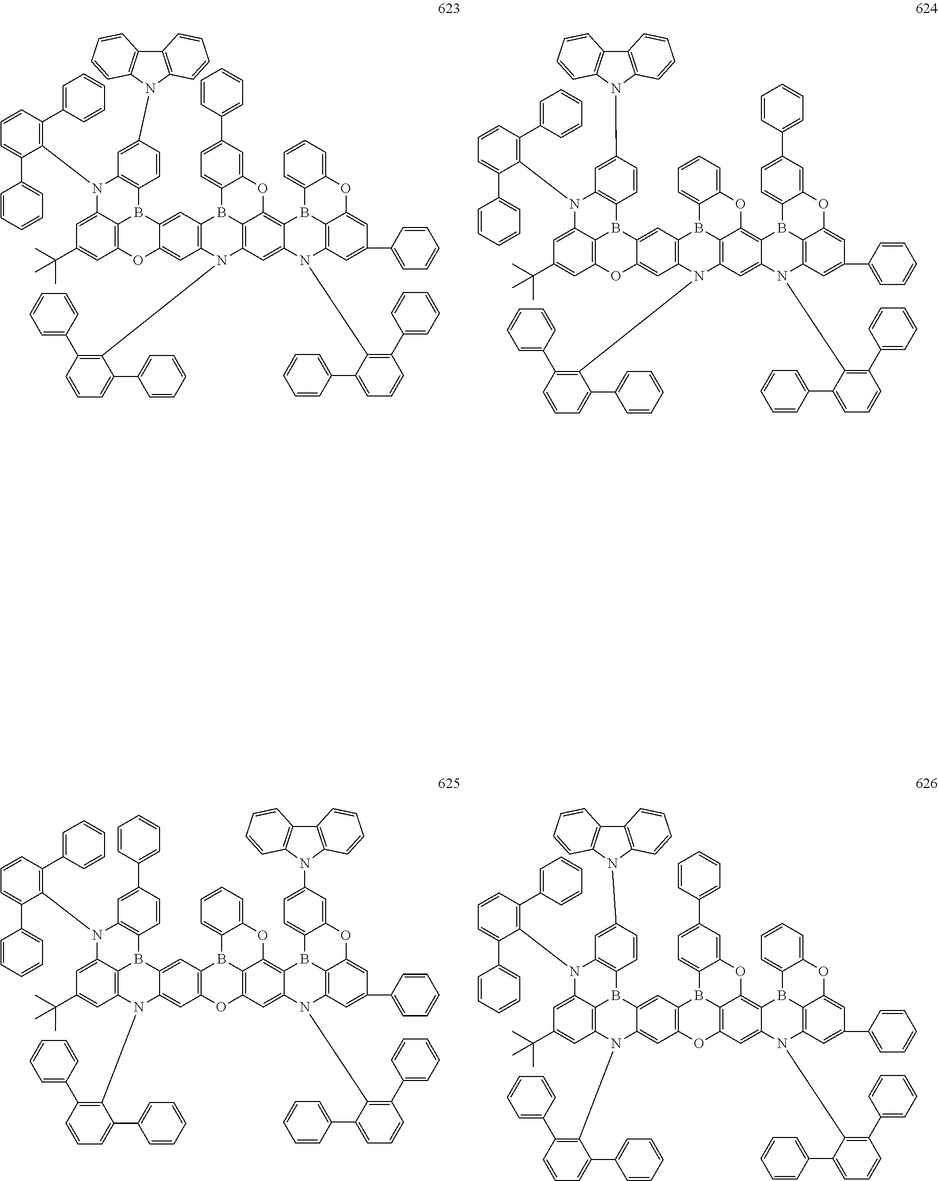 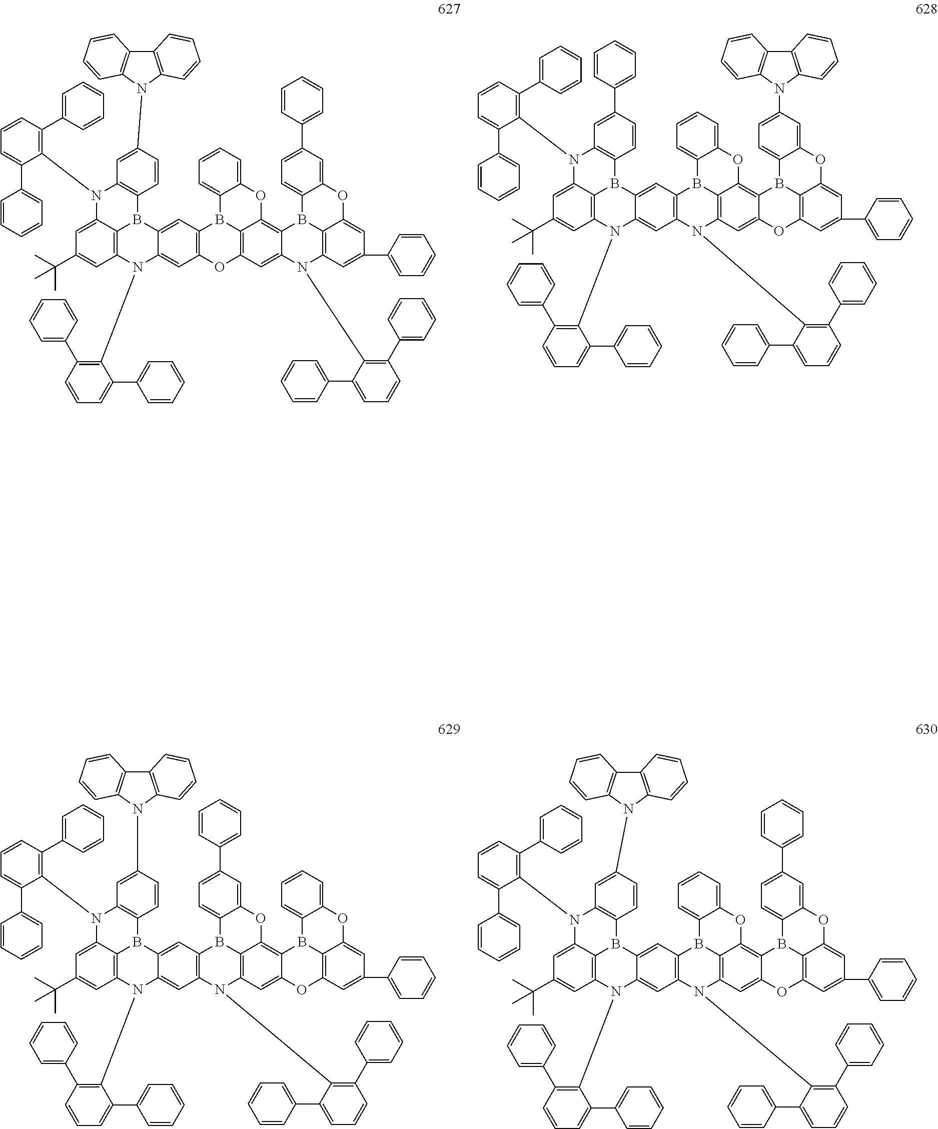 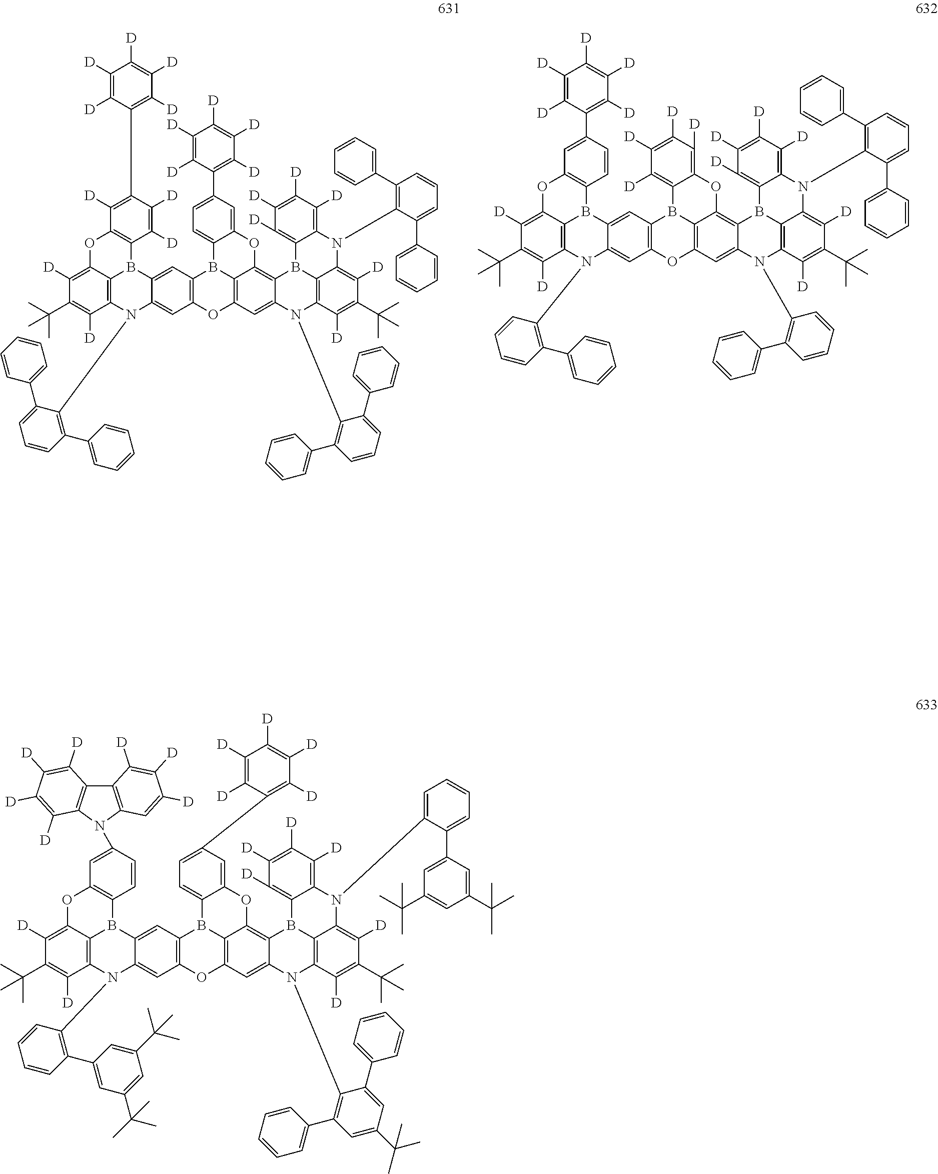 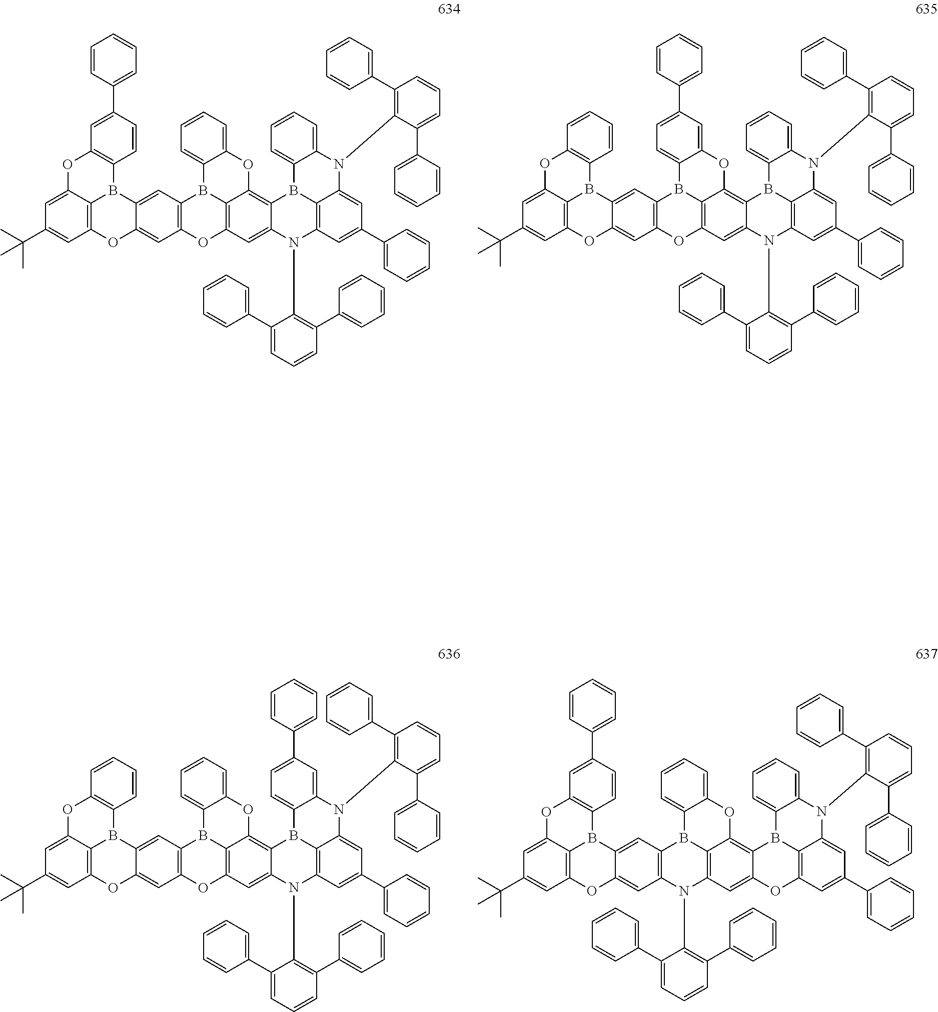 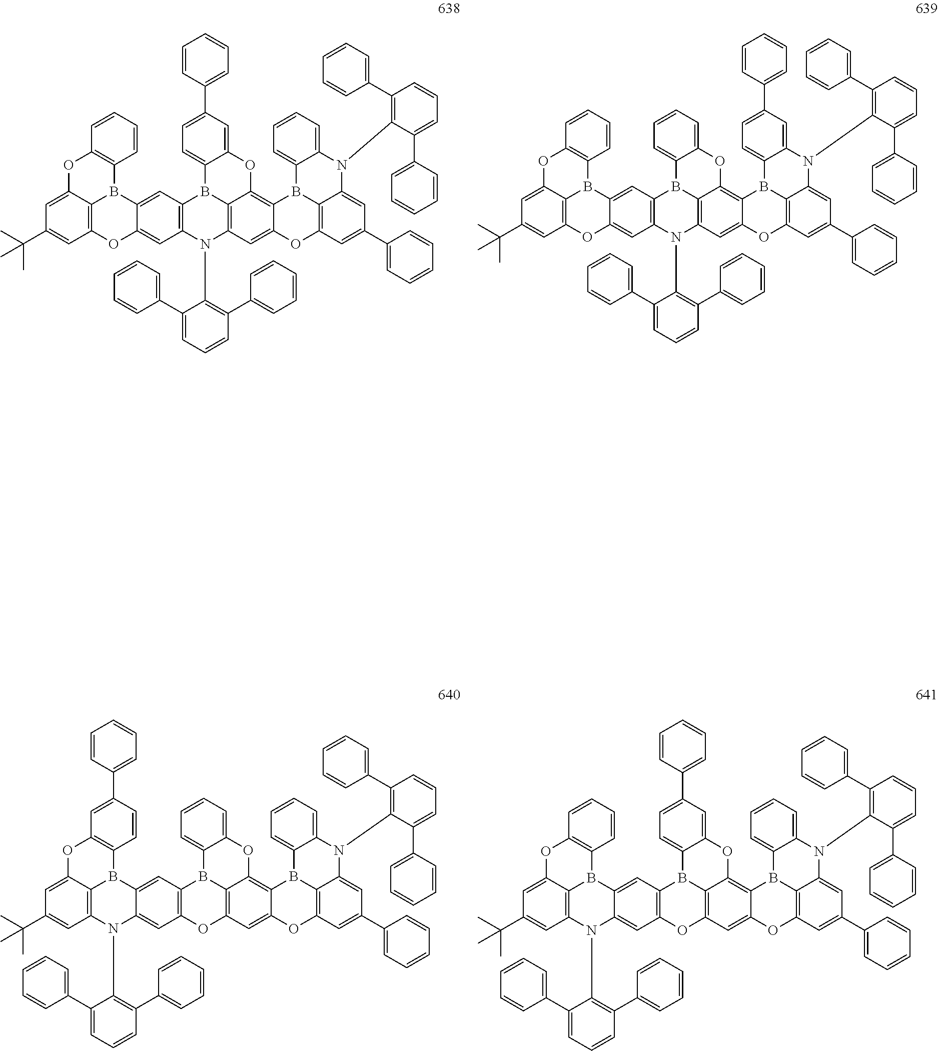 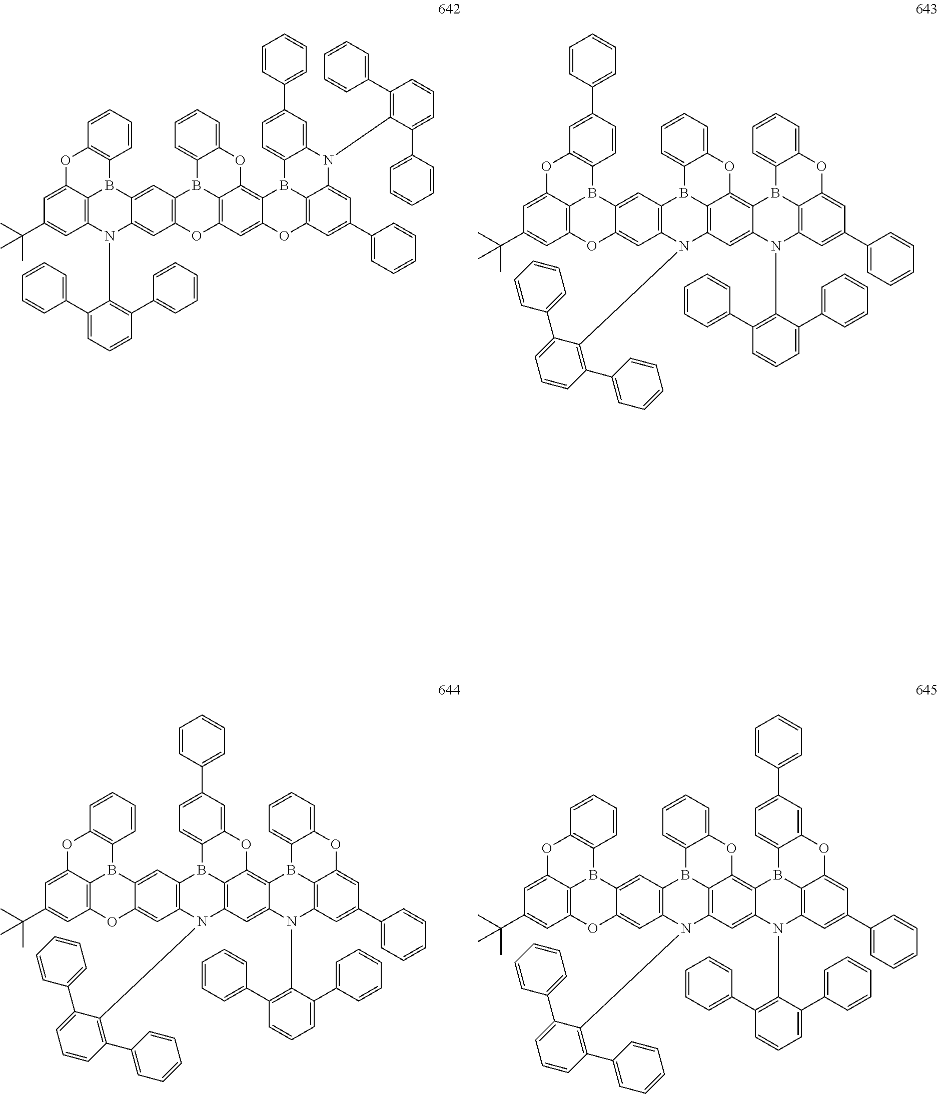 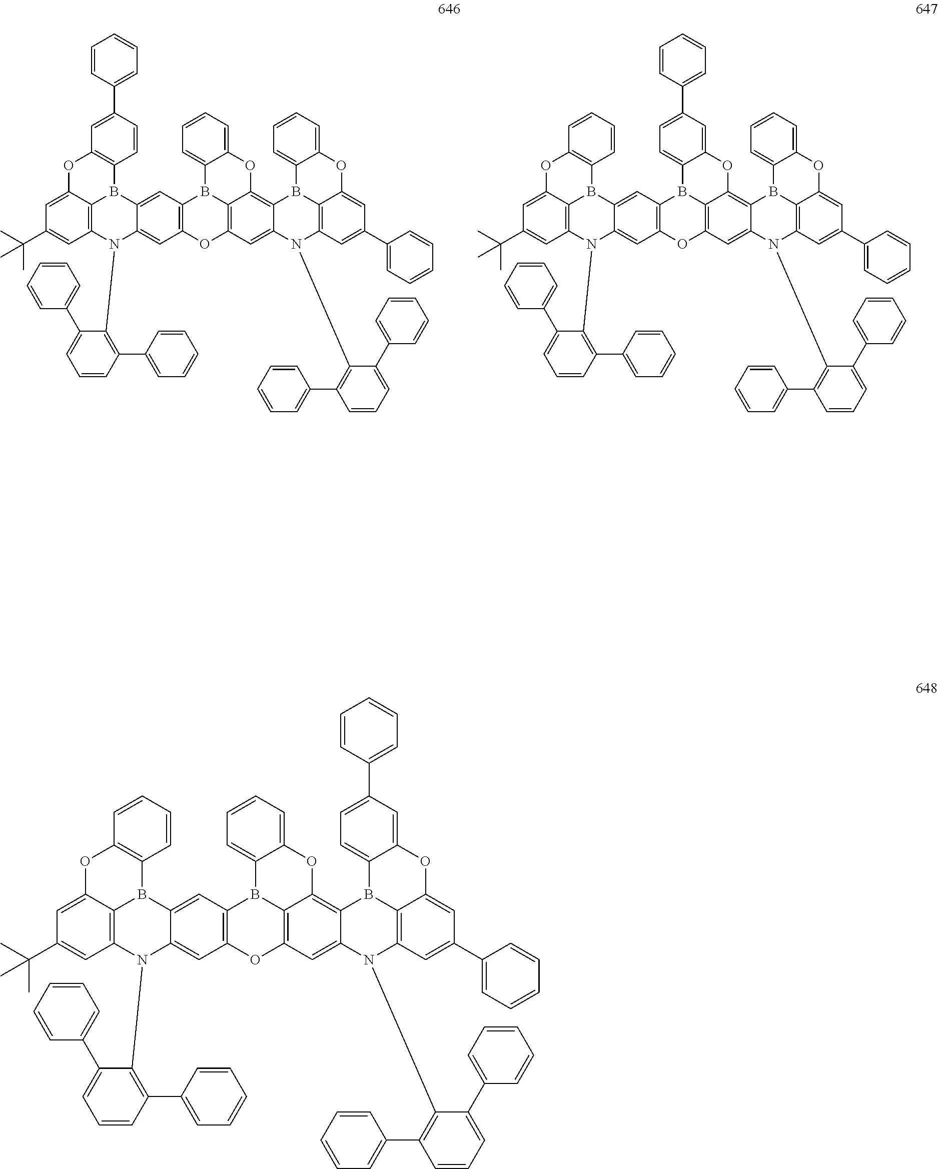 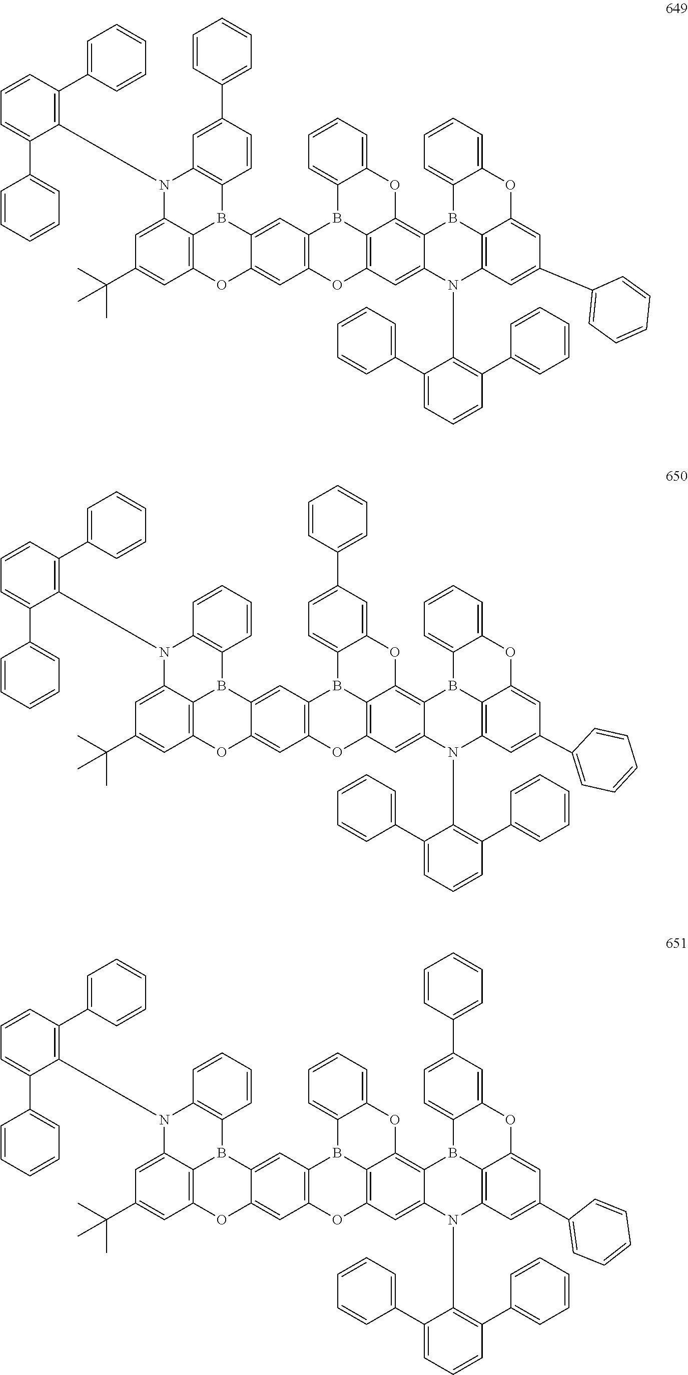 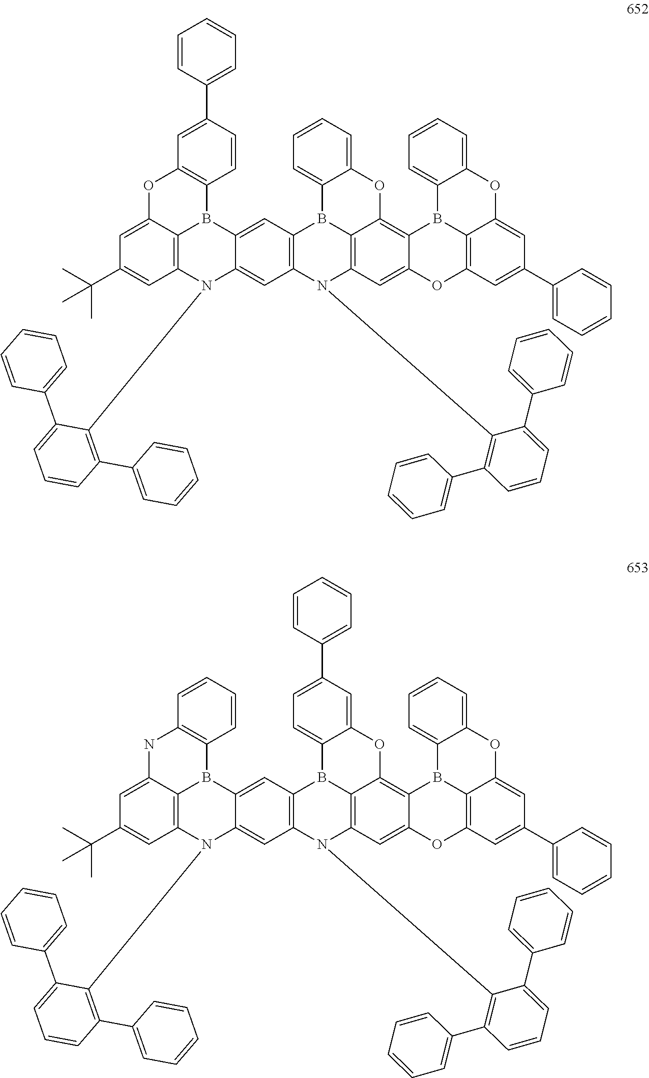 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1N2)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1O2] 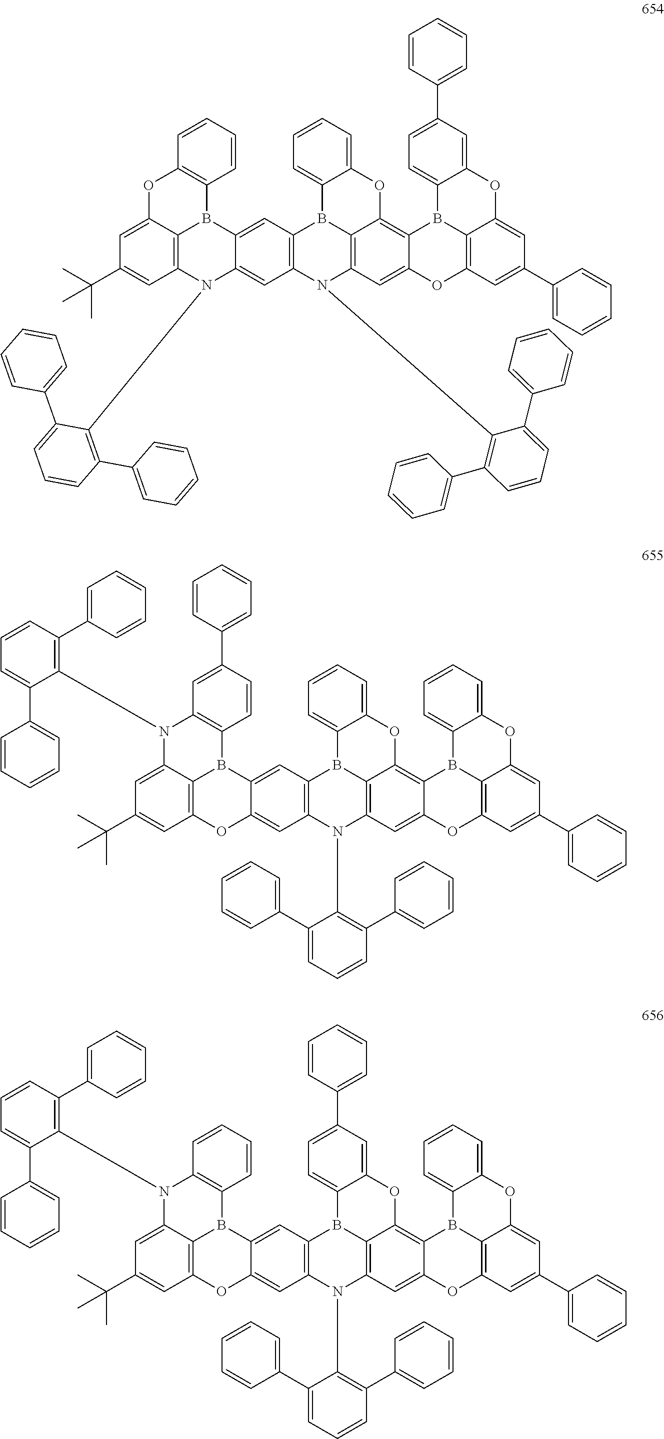 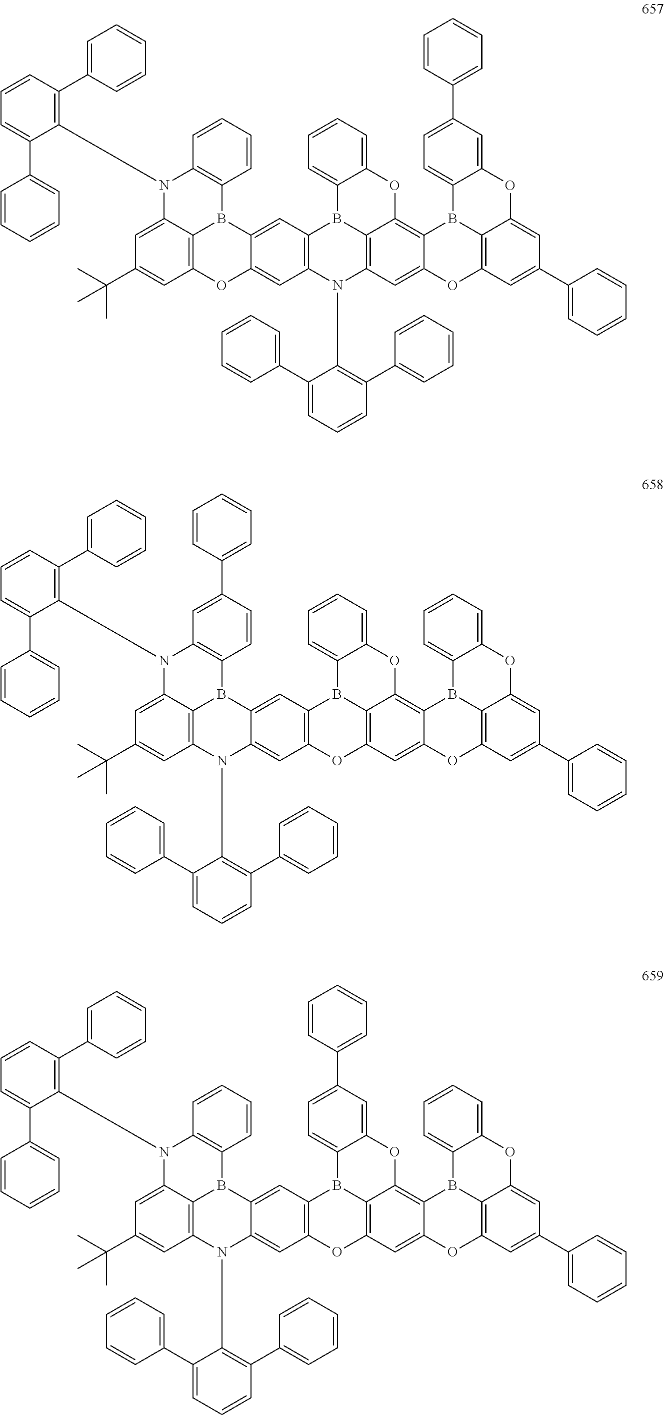 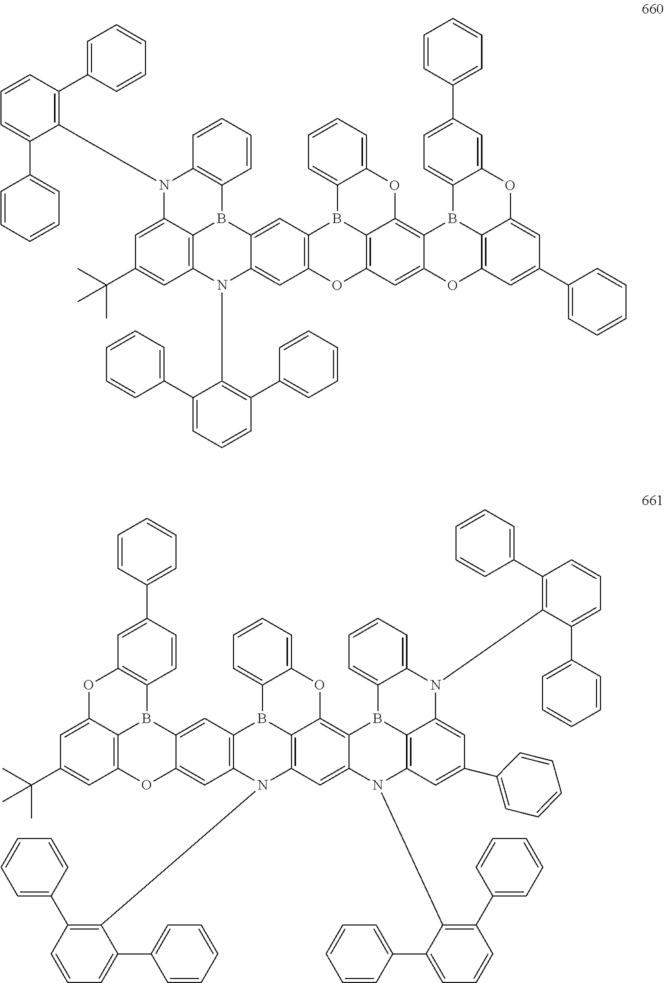 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c1c(cc1c2B2c3ccc(-c5ccccc5)cc3Oc3cc(-c5ccccc5)cc(c32)O1)O4 ; CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1] 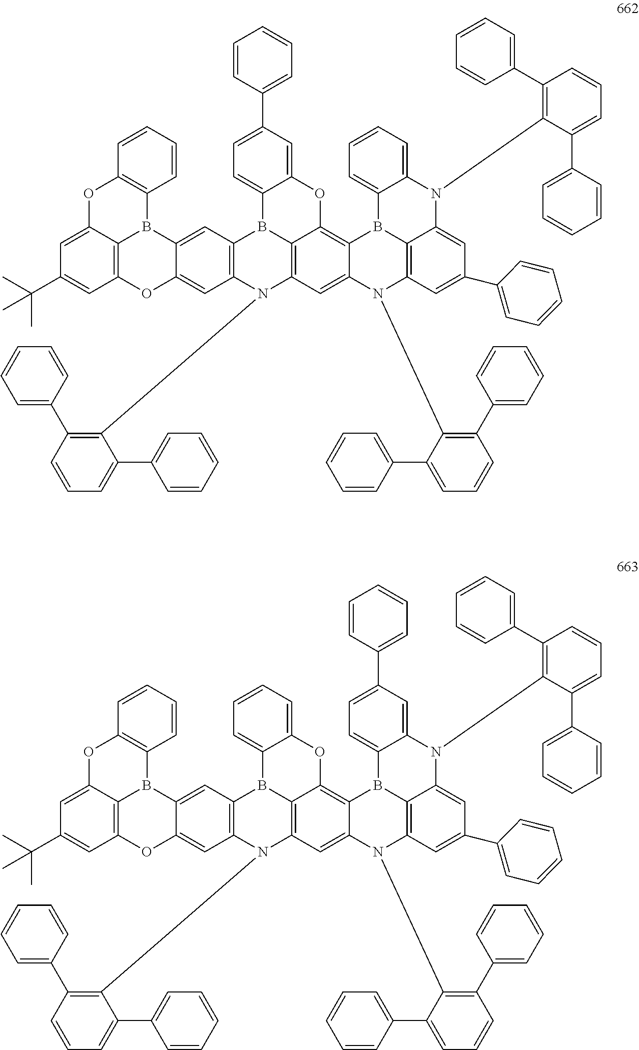 [SMILES: CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)N1c1c(-c2ccccc2)cccc1-c1ccccc1)N4c1c(-c2ccccc2)cccc1-c1ccccc1] 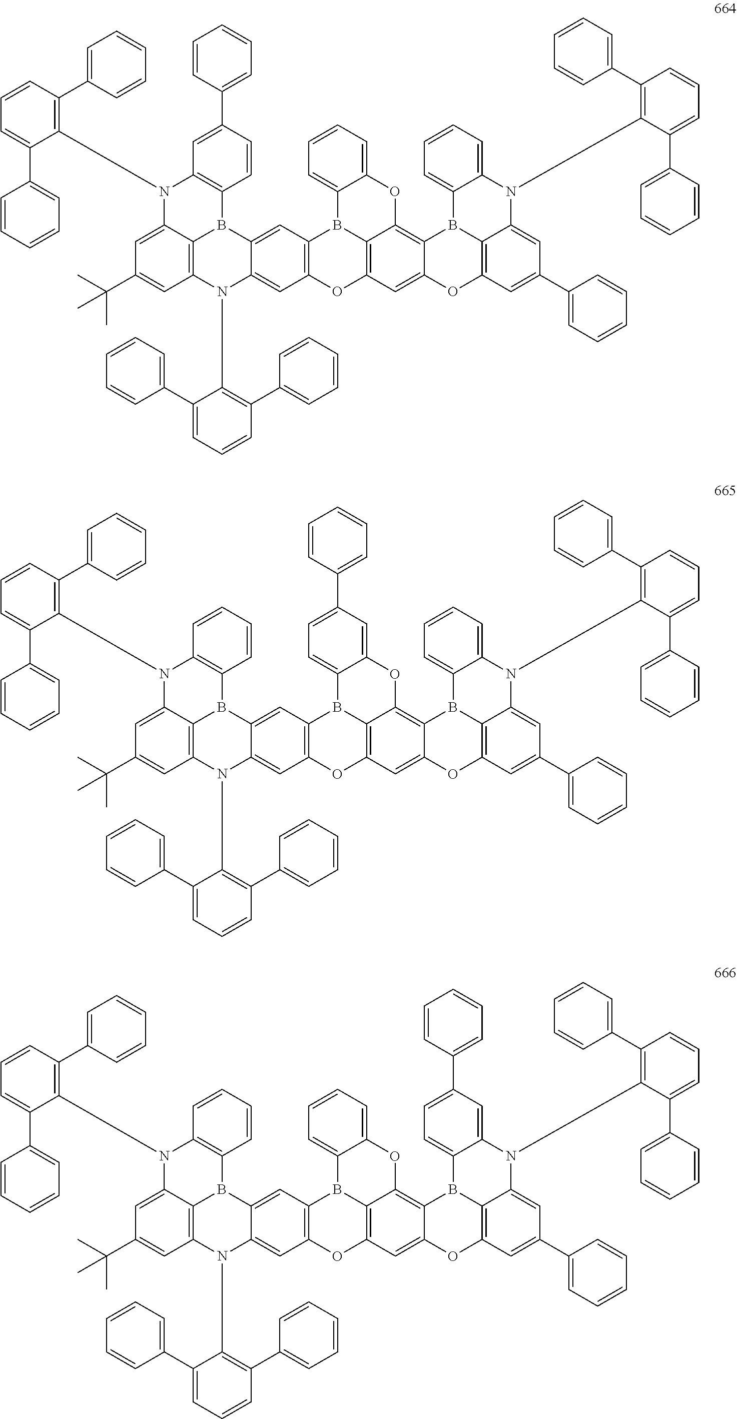 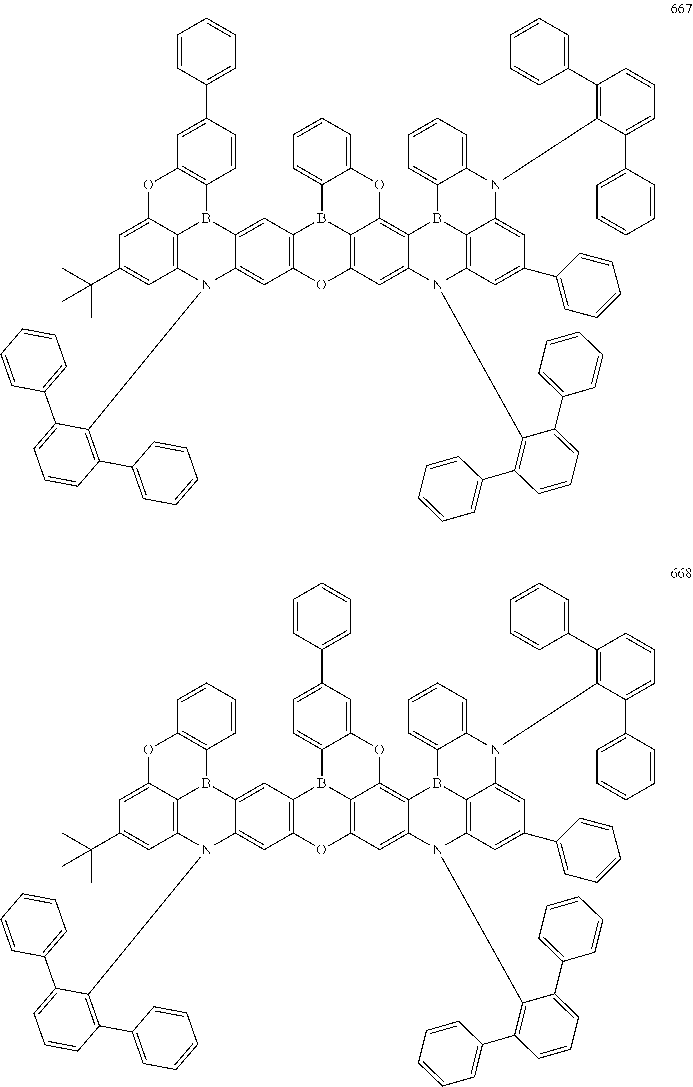 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4] 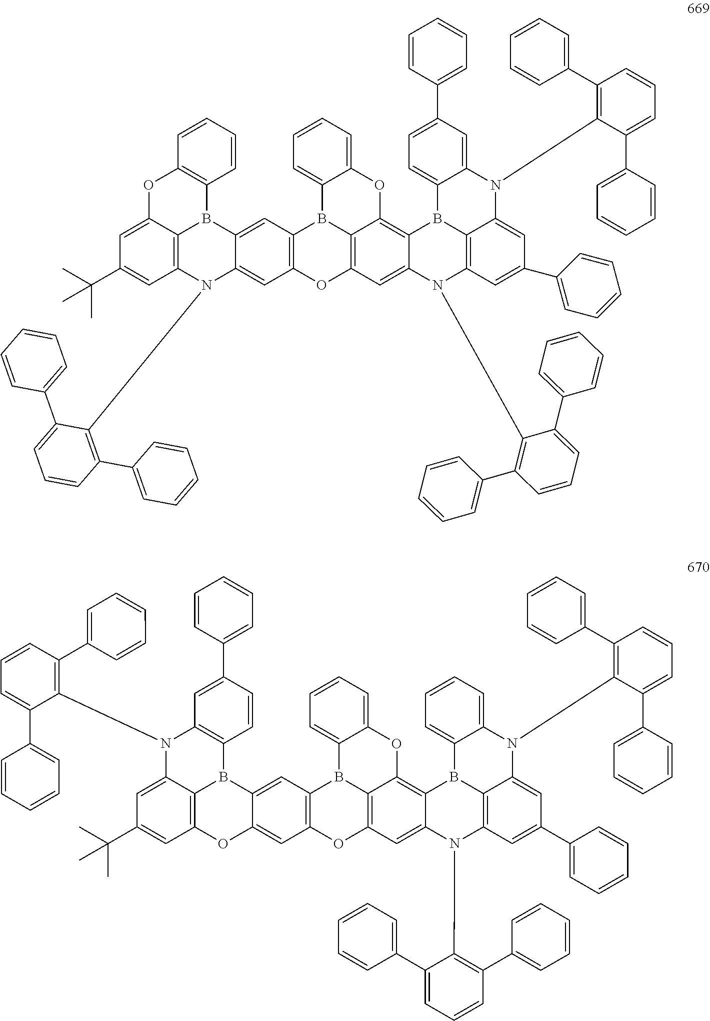 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccccc3N(c3c(-c4ccccc4)cccc3-c3ccccc3)c3cc(-c4ccccc4)cc(c31)N2c1c(-c2ccccc2)cccc1-c1ccccc1] 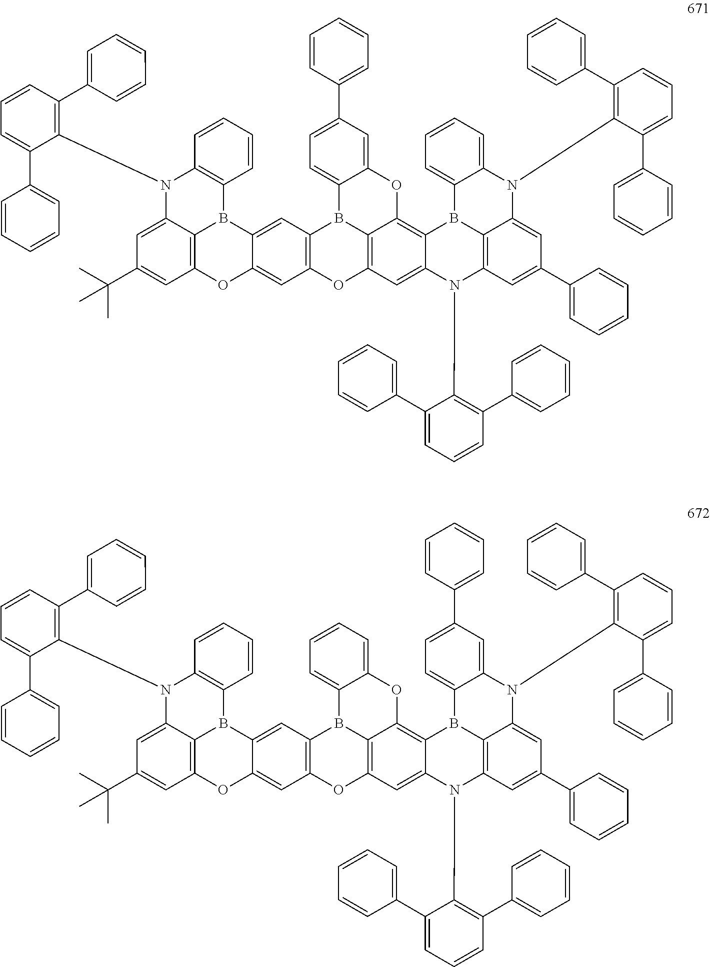 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(-c4ccccc4)cc(c31)N2c1c(-c2ccccc2)cccc1-c1ccccc1] 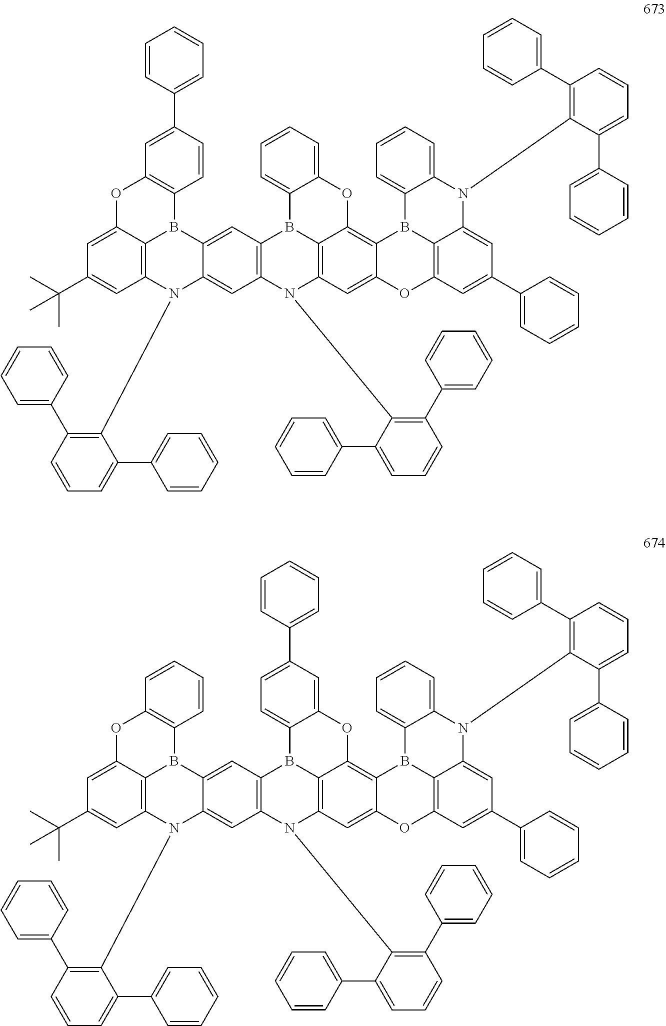 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1O2)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1N2c1c(-c2ccccc2)cccc1-c1ccccc1] 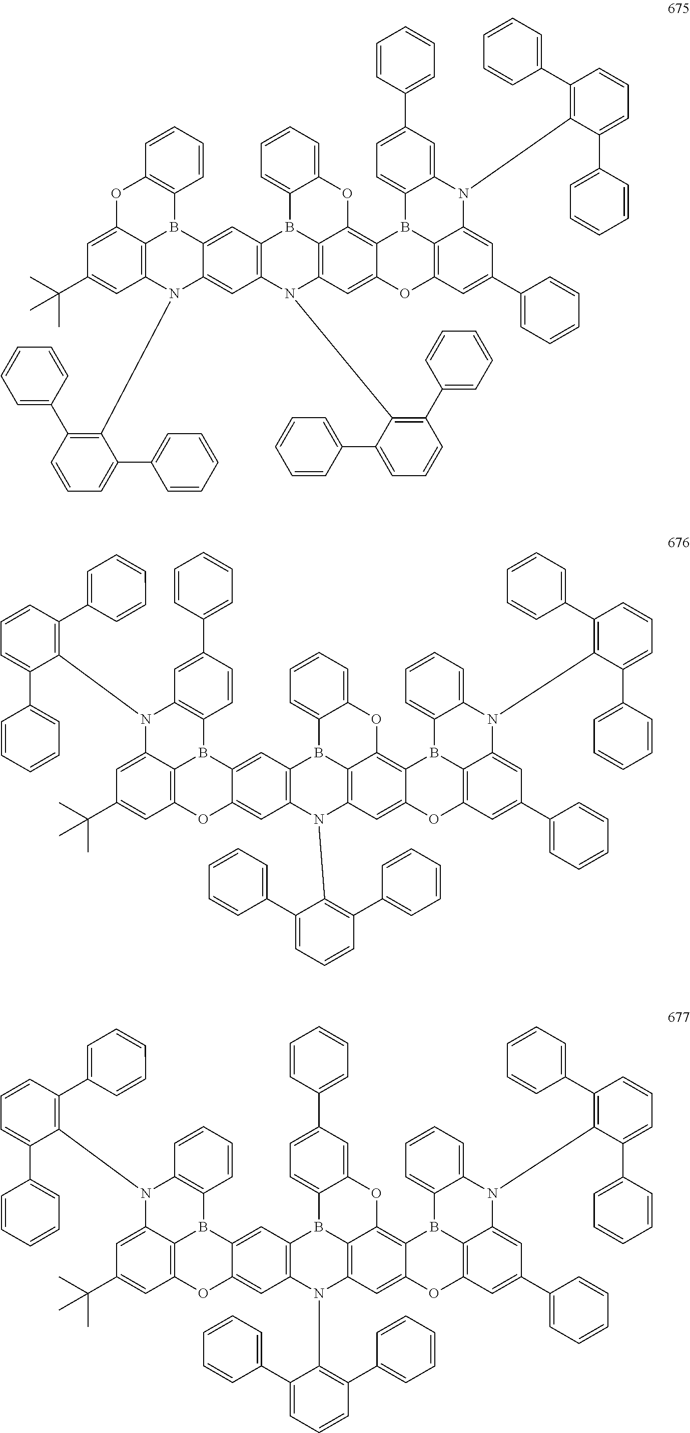 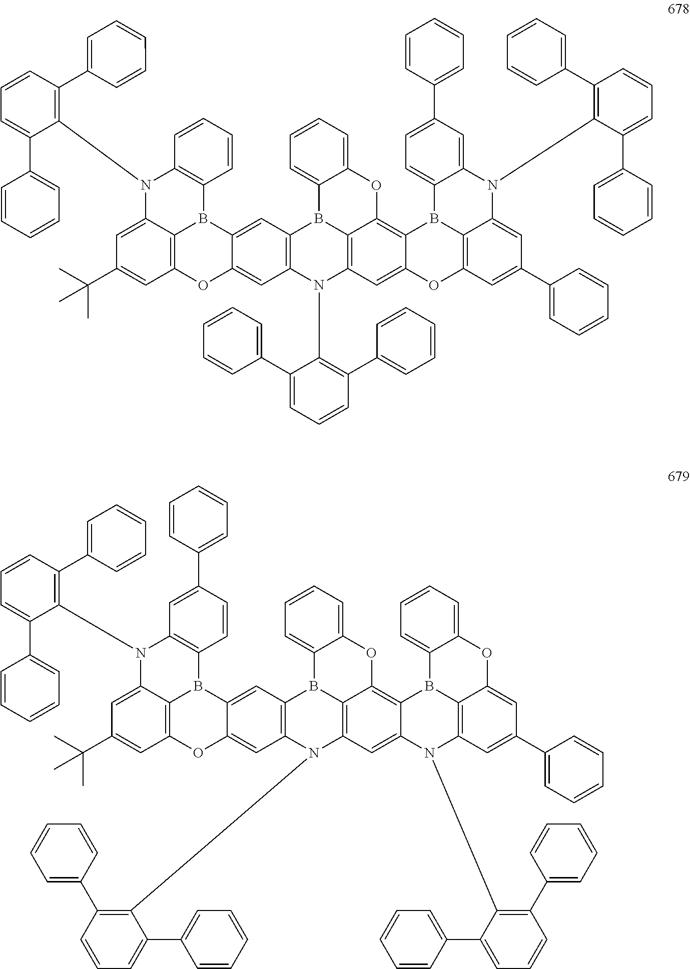 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc2c(c4c1B3c1ccccc1O4)B1c3ccc(-c4ccccc4)cc3N(c3c(-c4ccccc4)cccc3-c3ccccc3)c3cc(-c4ccccc4)cc(c31)O2 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccccc1O4)B1c3ccccc3Oc3cc(-c4ccccc4)cc(c31)N2c1c(-c2ccccc2)cccc1-c1ccccc1] 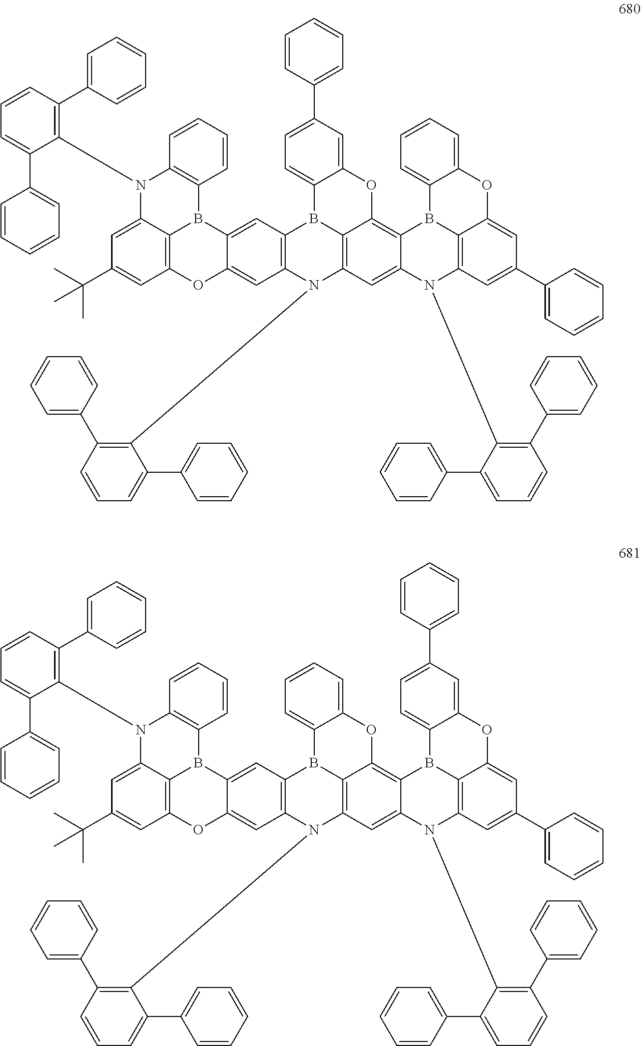 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc2c(c4c1B3c1ccc(-c3ccccc3)cc1O4)B1c3ccccc3Oc3cc(-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc2c(c4c1B3c1ccccc1O4)B1c3ccc(-c4ccccc4)cc3Oc3cc(-c4ccccc4)cc(c31)N2c1c(-c2ccccc2)cccc1-c1ccccc1] 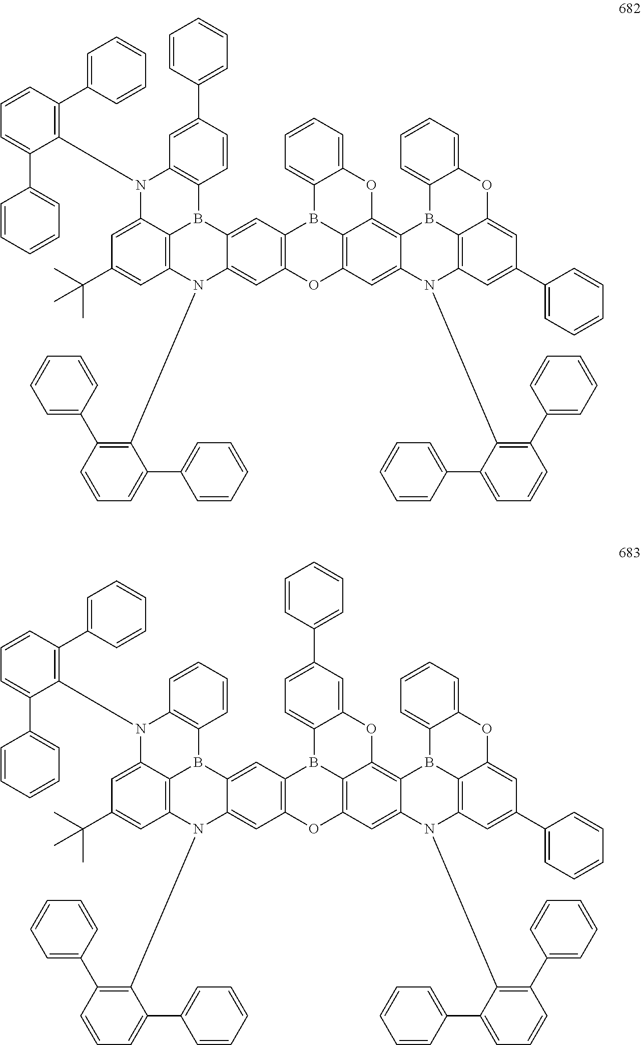 [SMILES: CC(C)(C)c1cc2c3c(c1)N(c1c(-c4ccccc4)cccc1-c1ccccc1)c1cc4c(cc1B3c1ccc(-c3ccccc3)cc1N2c1c(-c2ccccc2)cccc1-c1ccccc1)B1c2ccccc2Oc2c1c(cc1c2B2c3ccccc3Oc3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-c3ccccc3)cc2Oc2c1c(cc1c2B2c3ccccc3Oc3cc(-c5ccccc5)cc(c32)N1c1c(-c2ccccc2)cccc1-c1ccccc1)O4] 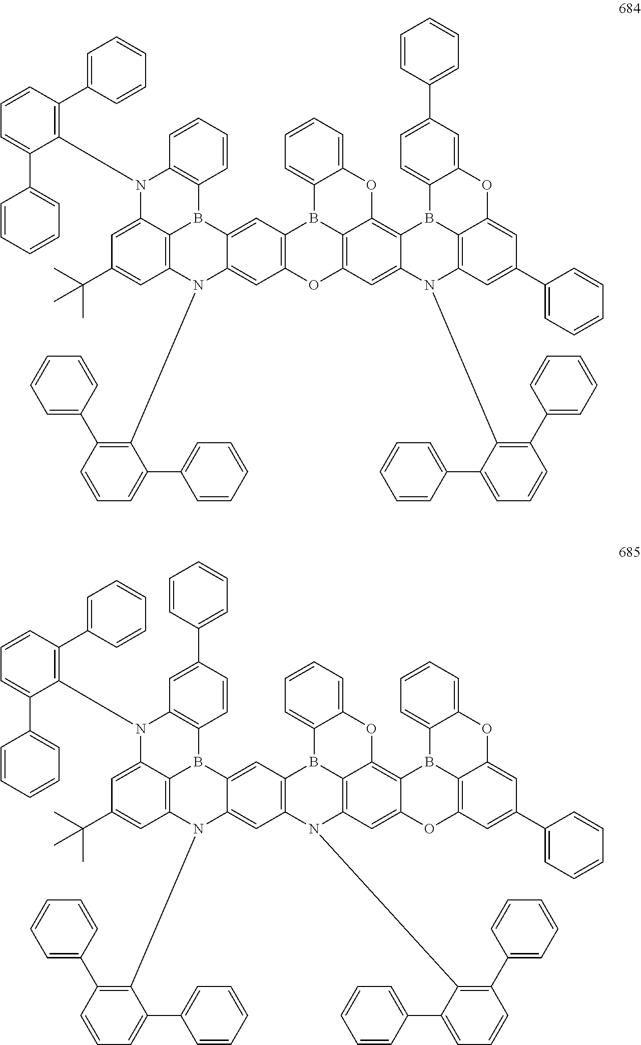 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c1c(cc1c2B2c3ccc(-c5ccccc5)cc3Oc3cc(-c5ccccc5)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccc(-c3ccccc3)cc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccccc1O2] 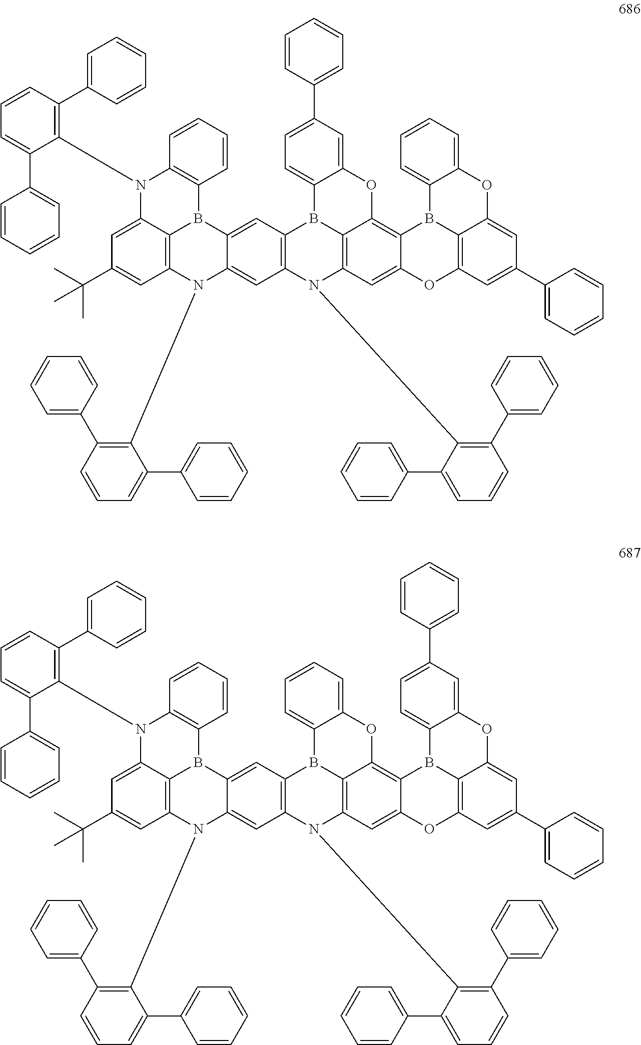 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-c3ccccc3)cc2Oc2c3c(cc(c21)N4c1c(-c2ccccc2)cccc1-c1ccccc1)Oc1cc(-c2ccccc2)cc2c1B3c1ccccc1O2 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c3c(cc(c21)N4c1c(-c2ccccc2)cccc1-c1ccccc1)Oc1cc(-c2ccccc2)cc2c1B3c1ccc(-c3ccccc3)cc1O2] 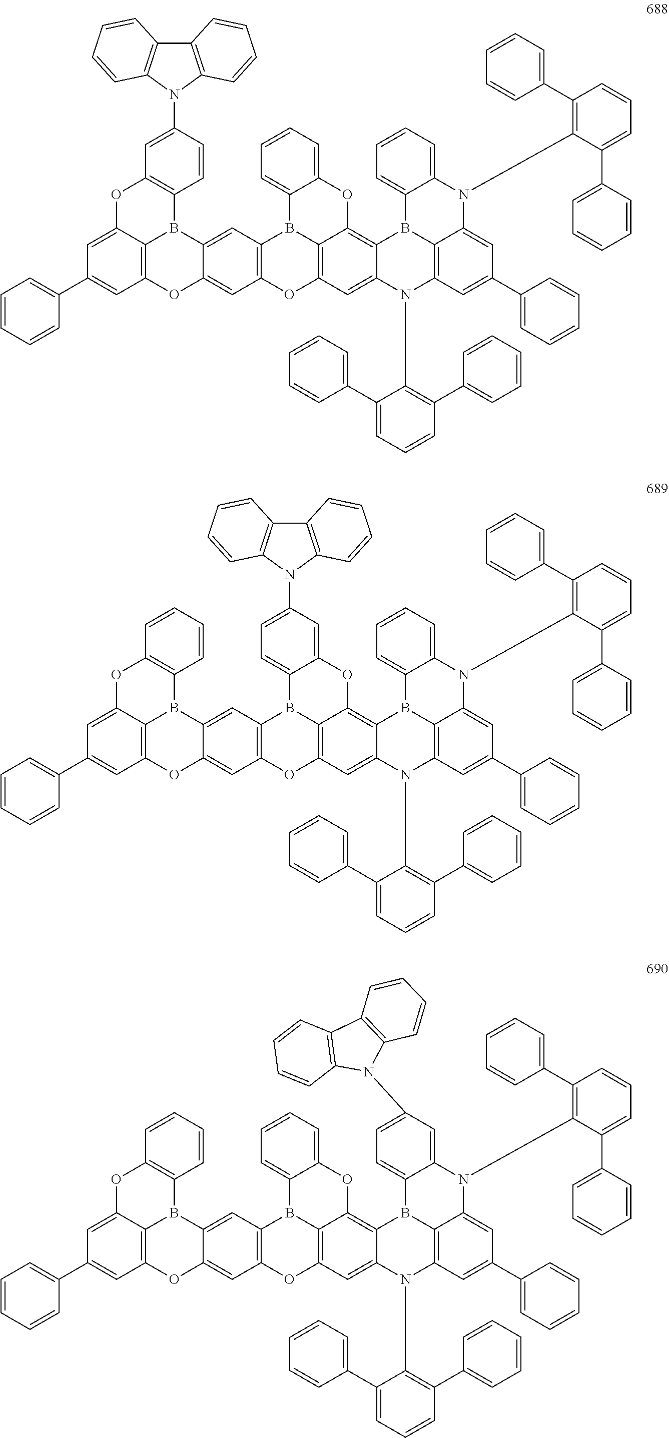 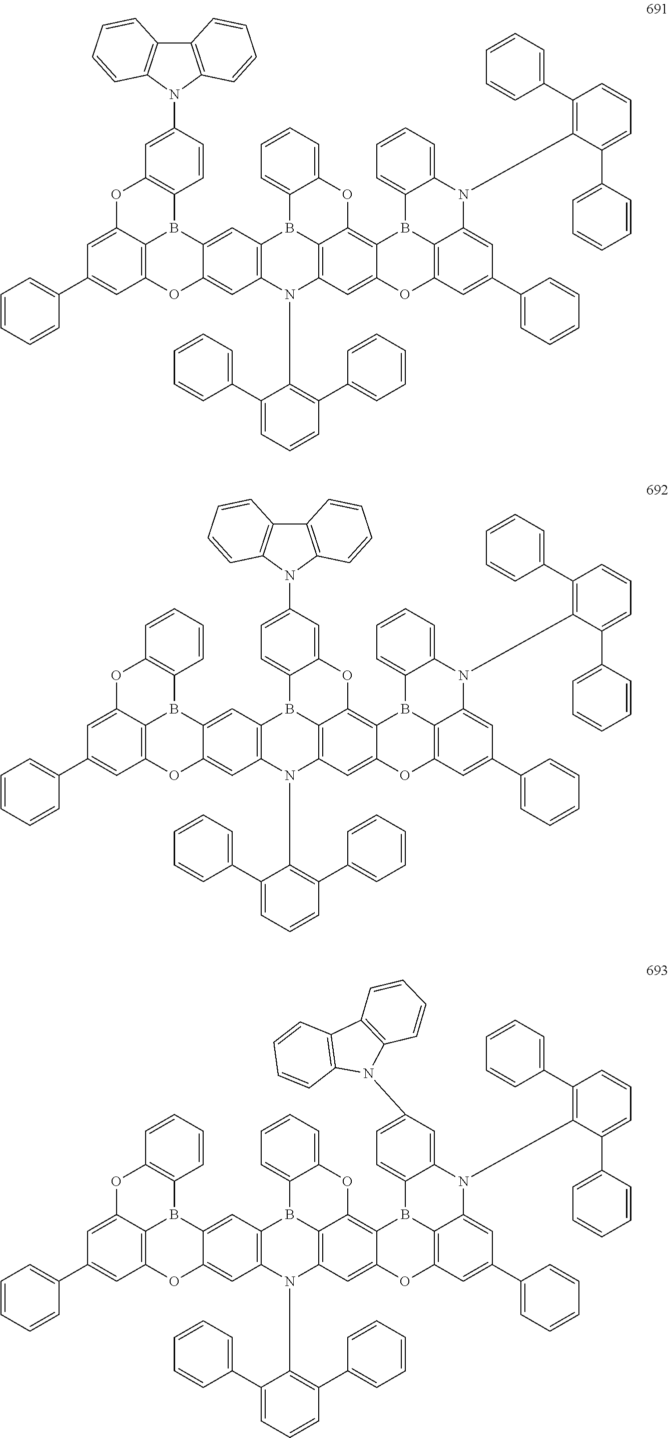 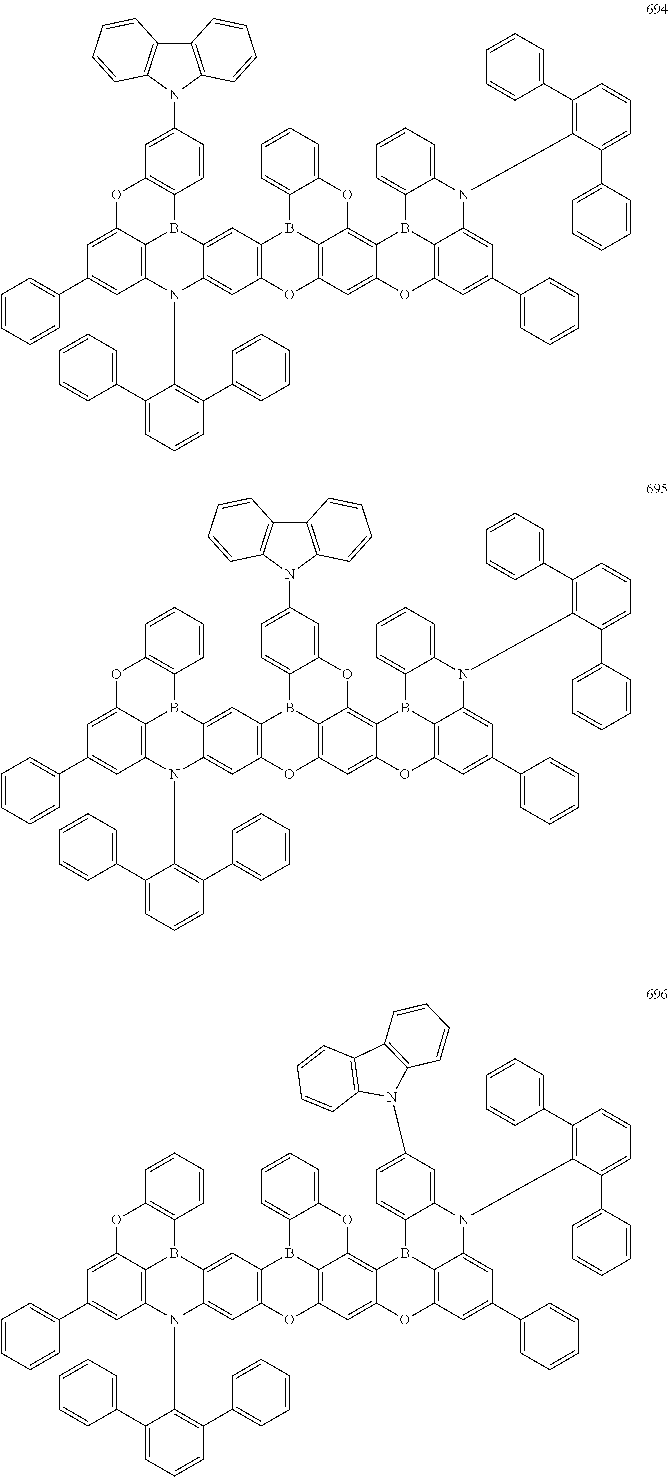 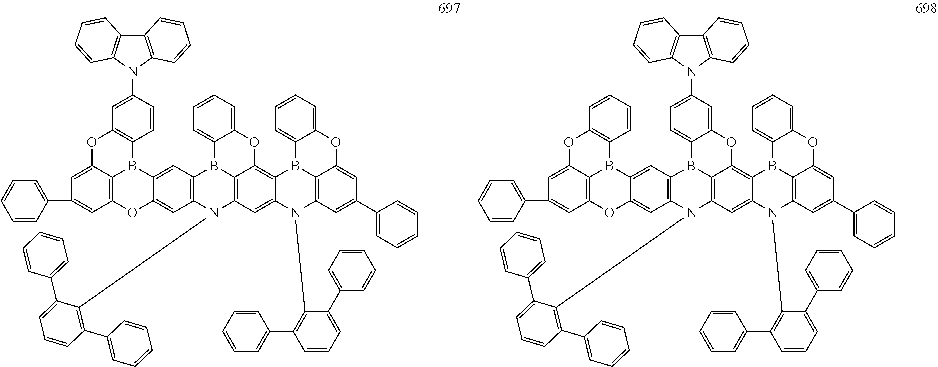 [SMILES: c1ccc(-c2cc3c4c(c2)Oc2cc5c(cc2B4c2ccc(-n4c6ccccc6c6ccccc64)cc2O3)B2c3ccccc3Oc3c2c(cc2c3B3c4ccccc4Oc4cc(-c6ccccc6)cc(c43)N2c2c(-c3ccccc3)cccc2-c2ccccc2)N5c2c(-c3ccccc3)cccc2-c2ccccc2)cc1 ; c1ccc(-c2cc3c4c(c2)Oc2cc5c(cc2B4c2ccccc2O3)B2c3ccc(-n4c6ccccc6c6ccccc64)cc3Oc3c2c(cc2c3B3c4ccccc4Oc4cc(-c6ccccc6)cc(c43)N2c2c(-c3ccccc3)cccc2-c2ccccc2)N5c2c(-c3ccccc3)cccc2-c2ccccc2)cc1] 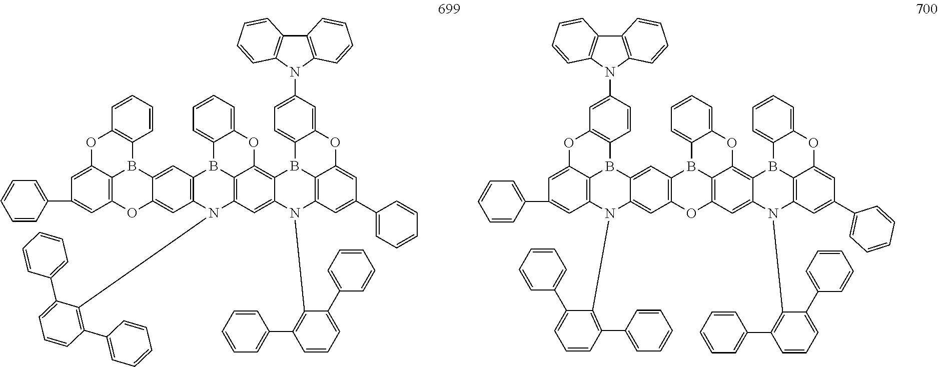 [SMILES: c1ccc(-c2cc3c4c(c2)Oc2cc5c(cc2B4c2ccccc2O3)B2c3ccccc3Oc3c2c(cc2c3B3c4ccc(-n6c7ccccc7c7ccccc76)cc4Oc4cc(-c6ccccc6)cc(c43)N2c2c(-c3ccccc3)cccc2-c2ccccc2)N5c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccc(-n4c6ccccc6c6ccccc64)cc2O3)B2c3ccccc3Oc3c2c(cc2c3B3c4ccccc4Oc4cc(-c6ccccc6)cc(c43)N2c2c(-c3ccccc3)cccc2-c2ccccc2)O5)cc1] 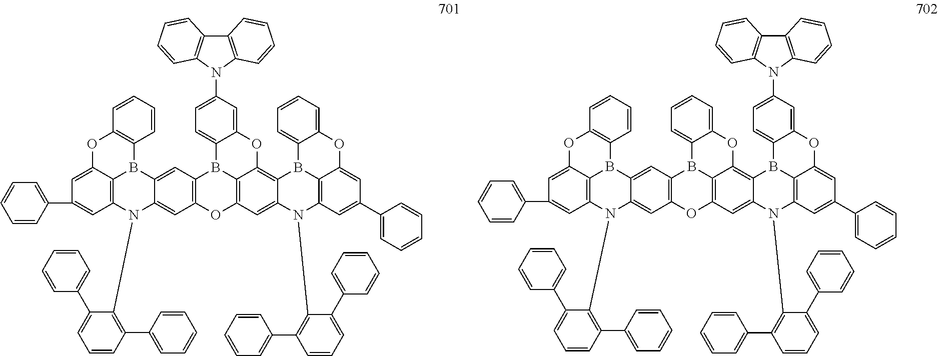 [SMILES: c1ccc(-c2cc3c4c(c2)N(c2c(-c5ccccc5)cccc2-c2ccccc2)c2cc5c(cc2B4c2ccccc2O3)B2c3ccc(-n4c6ccccc6c6ccccc64)cc3Oc3c2c(cc2c3B3c4ccccc4Oc4cc(-c6ccccc6)cc(c43)N2c2c(-c3ccccc3)cccc2-c2ccccc2)O5)cc1 ; c1ccc(-c2cc3c4c(c2)N(c2c(-c5ccccc5)cccc2-c2ccccc2)c2cc5c(cc2B4c2ccccc2O3)B2c3ccccc3Oc3c2c(cc2c3B3c4ccc(-n6c7ccccc7c7ccccc76)cc4Oc4cc(-c6ccccc6)cc(c43)N2c2c(-c3ccccc3)cccc2-c2ccccc2)O5)cc1] 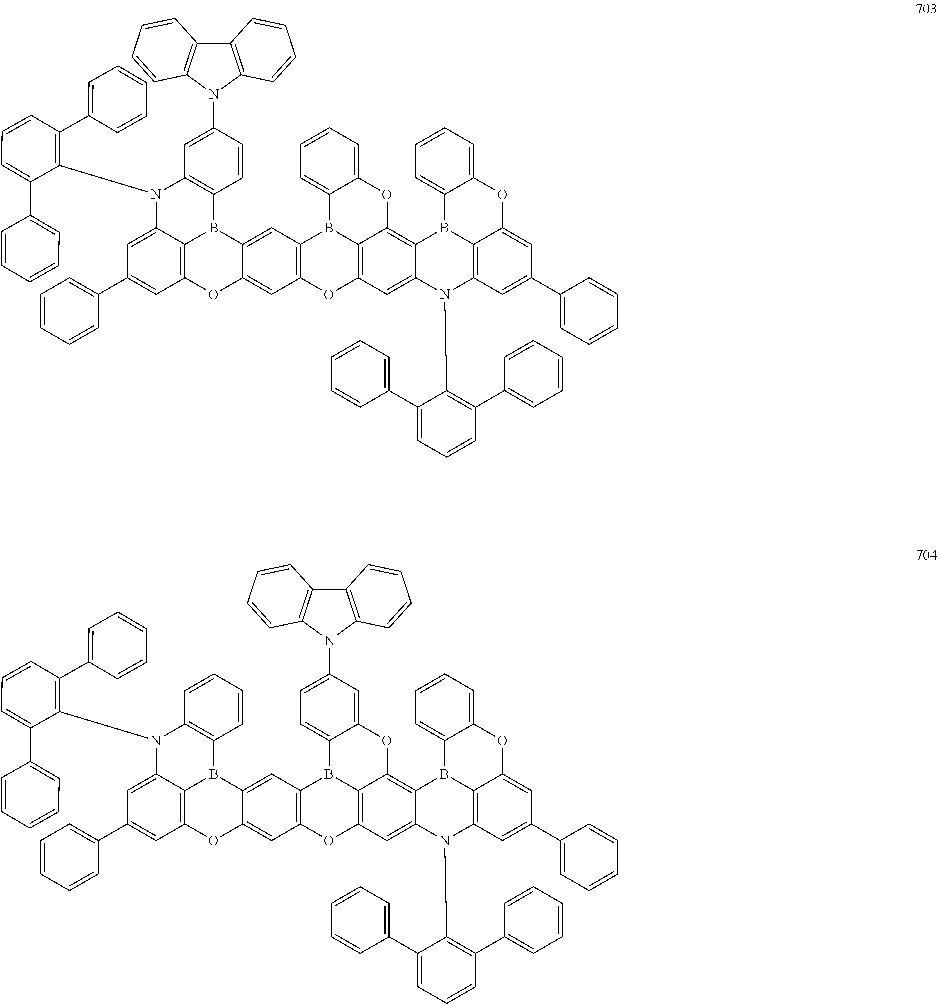 [SMILES: c1ccc(-c2cc3c4c(c2)N(c2c(-c5ccccc5)cccc2-c2ccccc2)c2cc(-n5c6ccccc6c6ccccc65)ccc2B4c2cc4c(cc2O3)Oc2cc3c(c5c2B4c2ccccc2O5)B2c4ccccc4Oc4cc(-c5ccccc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2ccccc2B4c2cc4c(cc2O3)Oc2cc3c(c5c2B4c2ccc(-n4c6ccccc6c6ccccc64)cc2O5)B2c4ccccc4Oc4cc(-c5ccccc5)cc(c42)N3c2c(-c3ccccc3)cccc2-c2ccccc2)cc1] 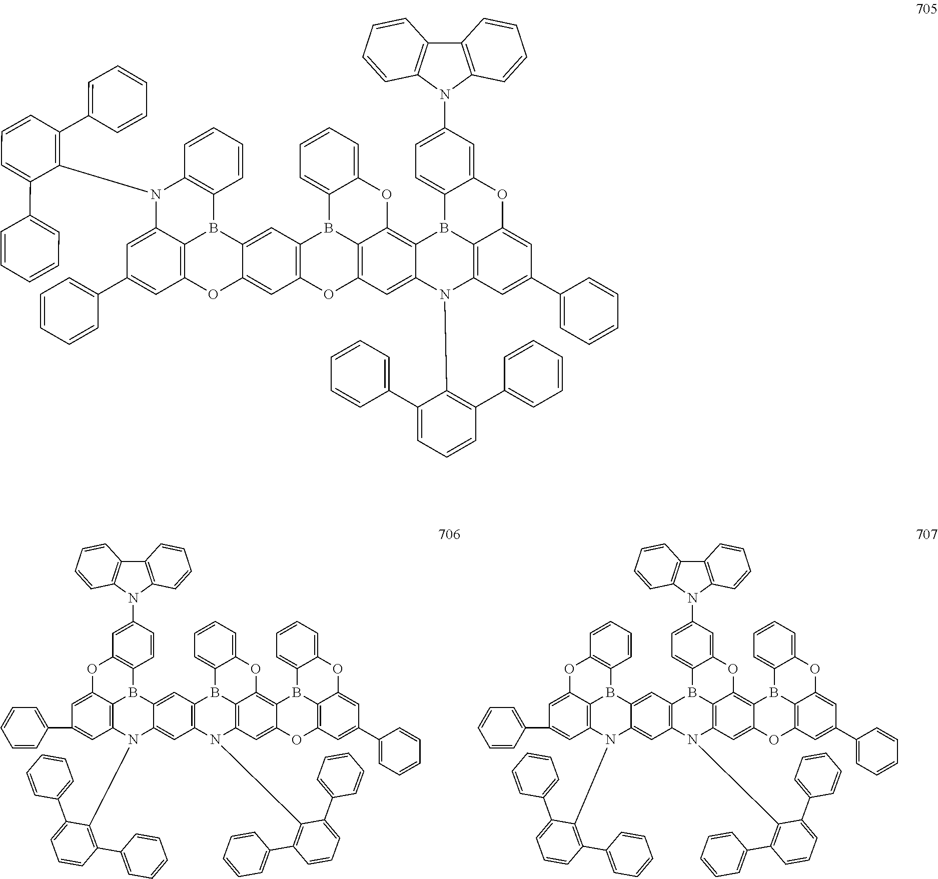 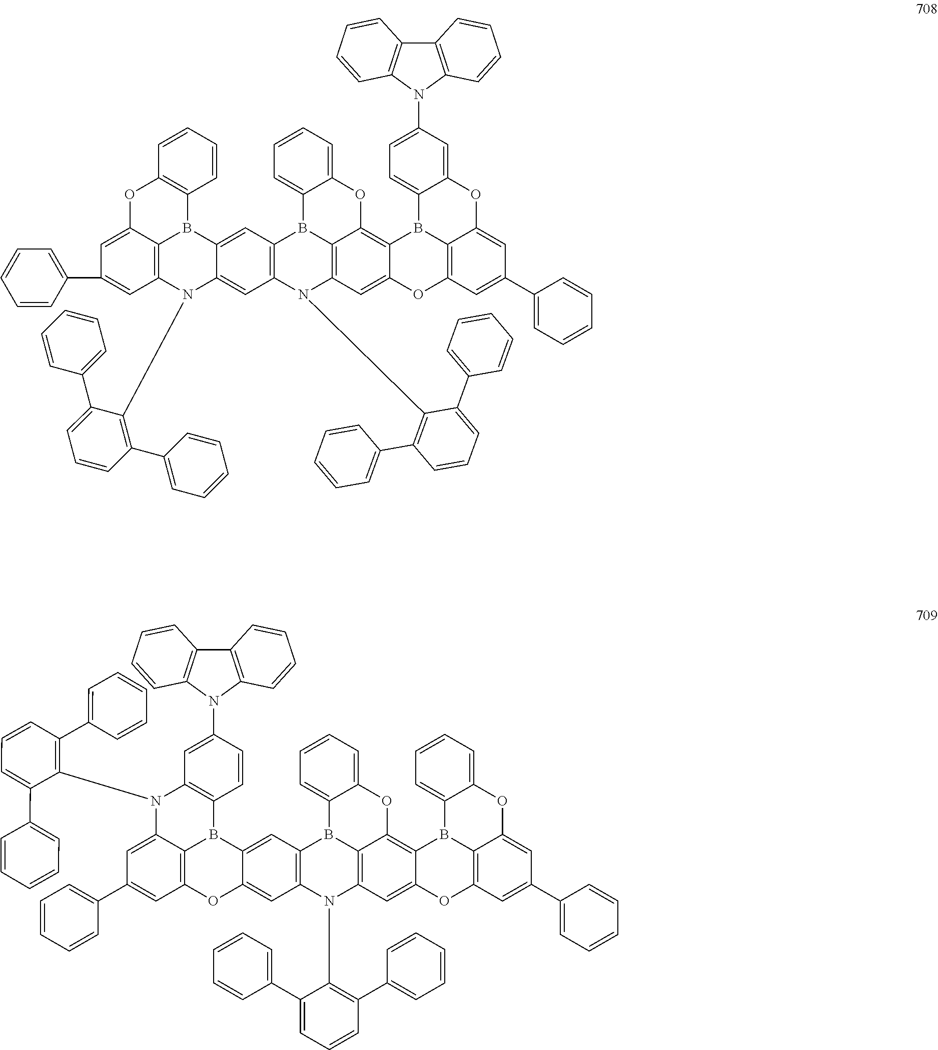 [SMILES: c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccccc2O4)cc1 ; c1ccc(-c2cc3c4c(c2)Oc2cc5c6c(c2B4c2ccccc2O3)Oc2ccccc2B6c2cc3c(cc2N5c2c(-c4ccccc4)cccc2-c2ccccc2)Oc2cc(-c4ccccc4)cc4c2B3c2ccc(-n3c5ccccc5c5ccccc53)cc2N4c2c(-c3ccccc3)cccc2-c2ccccc2)cc1] 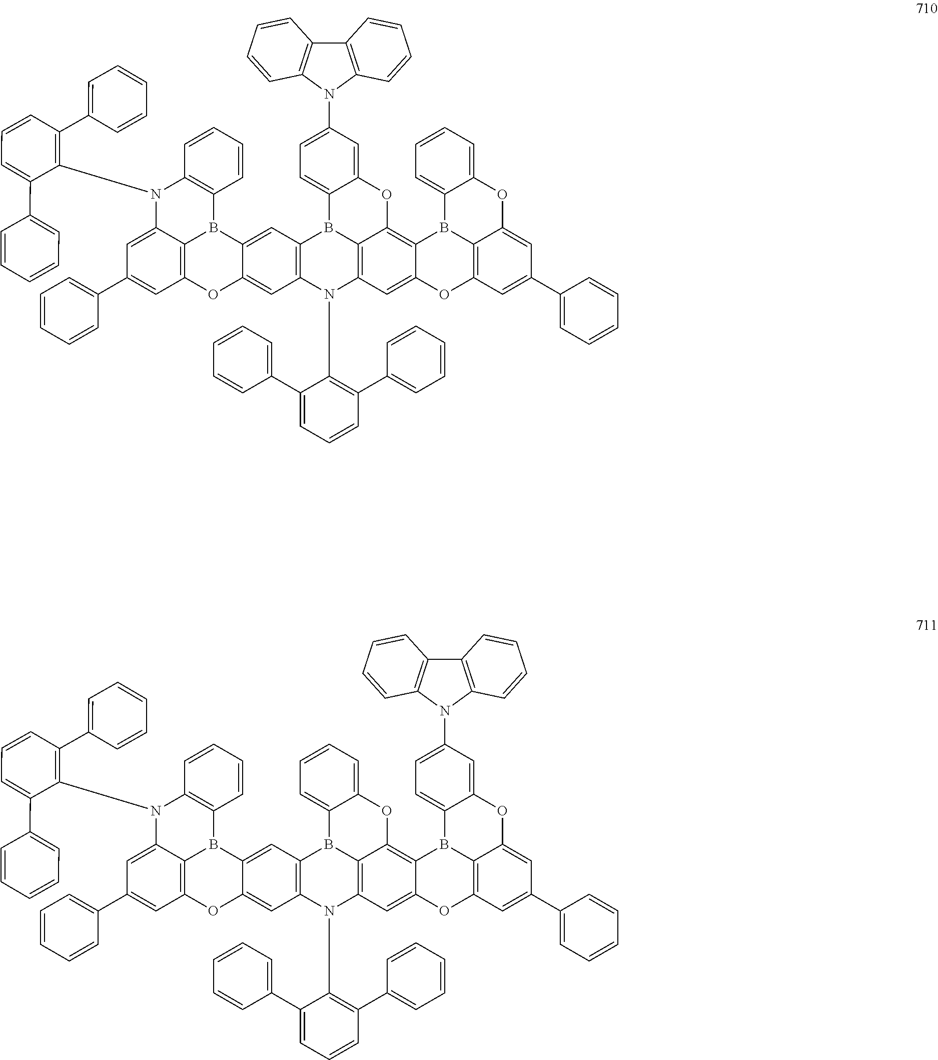 [SMILES: c1ccc(-c2cc3c4c(c2)Oc2cc5c6c(c2B4c2ccccc2O3)Oc2cc(-n3c4ccccc4c4ccccc43)ccc2B6c2cc3c(cc2N5c2c(-c4ccccc4)cccc2-c2ccccc2)Oc2cc(-c4ccccc4)cc4c2B3c2ccccc2N4c2c(-c3ccccc3)cccc2-c2ccccc2)cc1 ; c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)Oc2cc(-c4ccccc4)cc4c2B3c2ccccc2N4c2c(-c3ccccc3)cccc2-c2ccccc2)cc1] 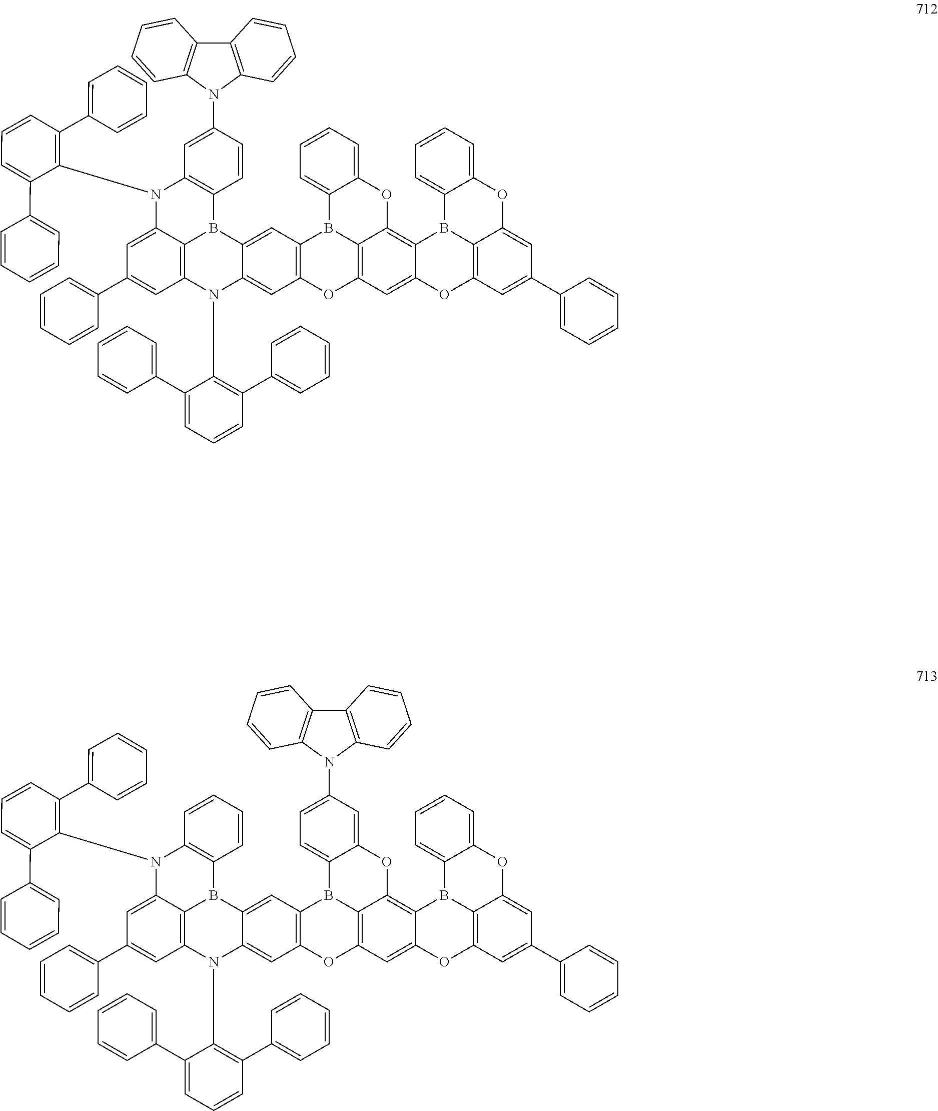 [SMILES: c1ccc(-c2cc3c4c(c2)Oc2cc5c6c(c2B4c2ccccc2O3)Oc2ccccc2B6c2cc3c(cc2O5)N(c2c(-c4ccccc4)cccc2-c2ccccc2)c2cc(-c4ccccc4)cc4c2B3c2ccc(-n3c5ccccc5c5ccccc53)cc2N4c2c(-c3ccccc3)cccc2-c2ccccc2)cc1 ; c1ccc(-c2cc3c4c(c2)Oc2cc5c6c(c2B4c2ccccc2O3)Oc2cc(-n3c4ccccc4c4ccccc43)ccc2B6c2cc3c(cc2O5)N(c2c(-c4ccccc4)cccc2-c2ccccc2)c2cc(-c4ccccc4)cc4c2B3c2ccccc2N4c2c(-c3ccccc3)cccc2-c2ccccc2)cc1] 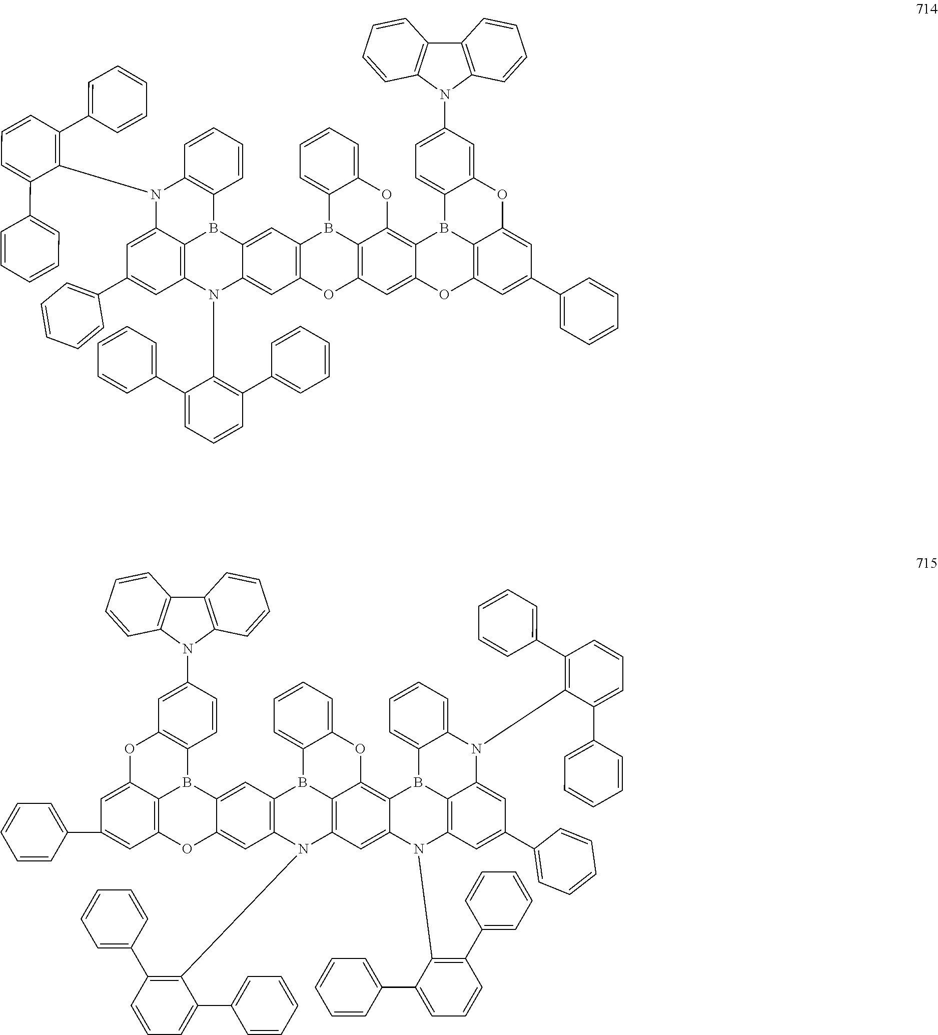 [SMILES: c1ccc(-c2cc3c4c(c2)Oc2cc5c6c(c2B4c2ccc(-n4c7ccccc7c7ccccc74)cc2O3)Oc2ccccc2B6c2cc3c(cc2O5)N(c2c(-c4ccccc4)cccc2-c2ccccc2)c2cc(-c4ccccc4)cc4c2B3c2ccccc2N4c2c(-c3ccccc3)cccc2-c2ccccc2)cc1 ; c1ccc(-c2cc3c4c(c2)Oc2cc5c(cc2B4c2ccc(-n4c6ccccc6c6ccccc64)cc2O3)B2c3ccccc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1] 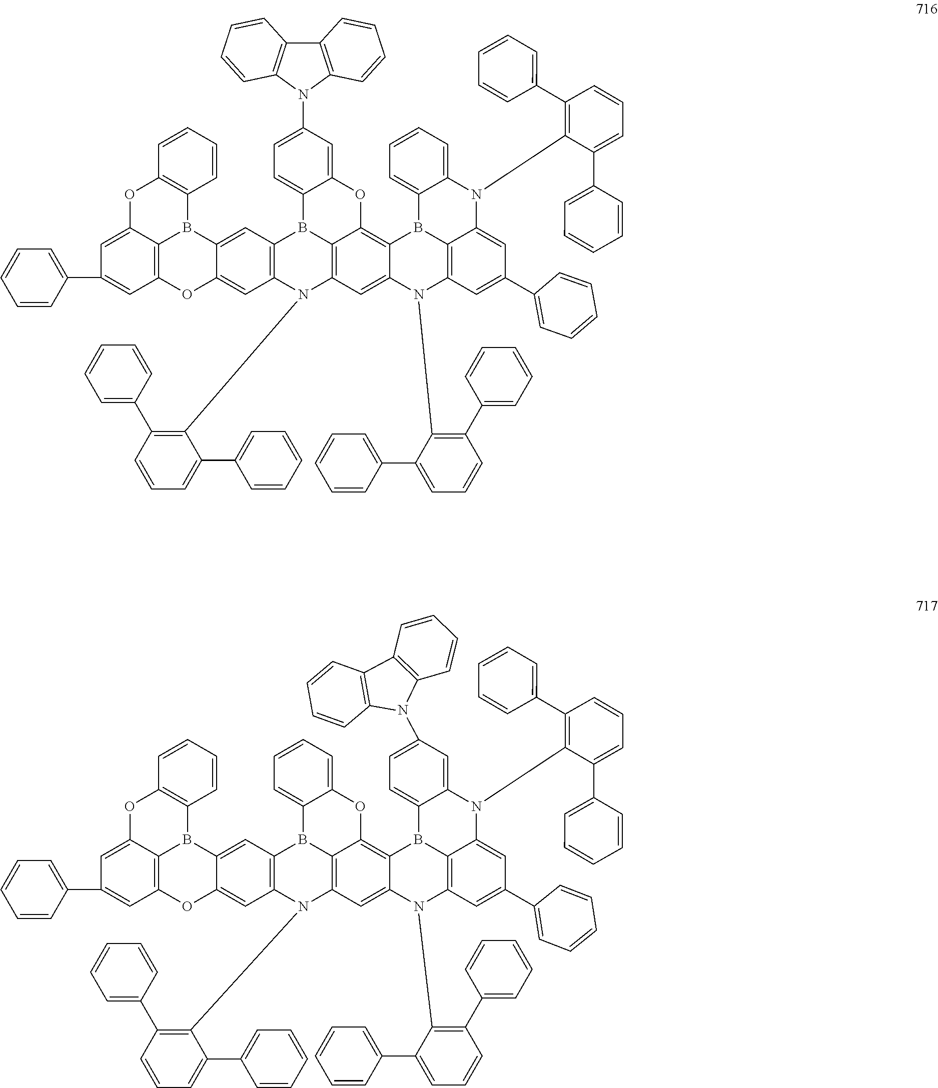 [SMILES: c1ccc(-c2cc3c4c(c2)Oc2cc5c(cc2B4c2ccccc2O3)B2c3ccc(-n4c6ccccc6c6ccccc64)cc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1 ; c1ccc(-c2cc3c4c(c2)Oc2cc5c(cc2B4c2ccccc2O3)B2c3ccccc3Oc3c2c(cc2c3B3c4ccc(-n6c7ccccc7c7ccccc76)cc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1] 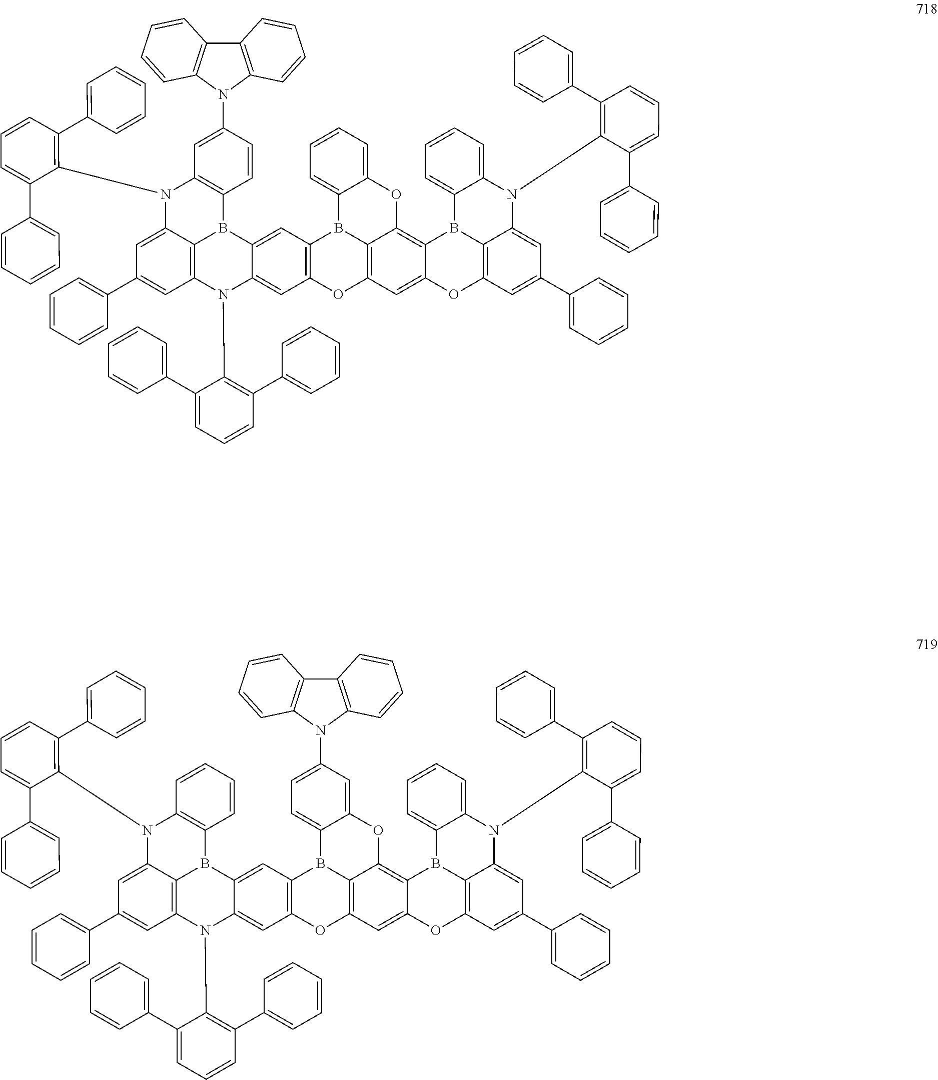 [SMILES: c1ccc(-c2cc3c4c(c2)N(c2c(-c5ccccc5)cccc2-c2ccccc2)c2ccccc2B4c2c(cc4c5c2Oc2ccccc2B5c2cc5c(cc2O4)N(c2c(-c4ccccc4)cccc2-c2ccccc2)c2cc(-c4ccccc4)cc4c2B5c2ccc(-n5c6ccccc6c6ccccc65)cc2N4c2c(-c4ccccc4)cccc2-c2ccccc2)O3)cc1 ; c1ccc(-c2cc3c4c(c2)N(c2c(-c5ccccc5)cccc2-c2ccccc2)c2ccccc2B4c2c(cc4c5c2Oc2cc(-n6c7ccccc7c7ccccc76)ccc2B5c2cc5c(cc2O4)N(c2c(-c4ccccc4)cccc2-c2ccccc2)c2cc(-c4ccccc4)cc4c2B5c2ccccc2N4c2c(-c4ccccc4)cccc2-c2ccccc2)O3)cc1] 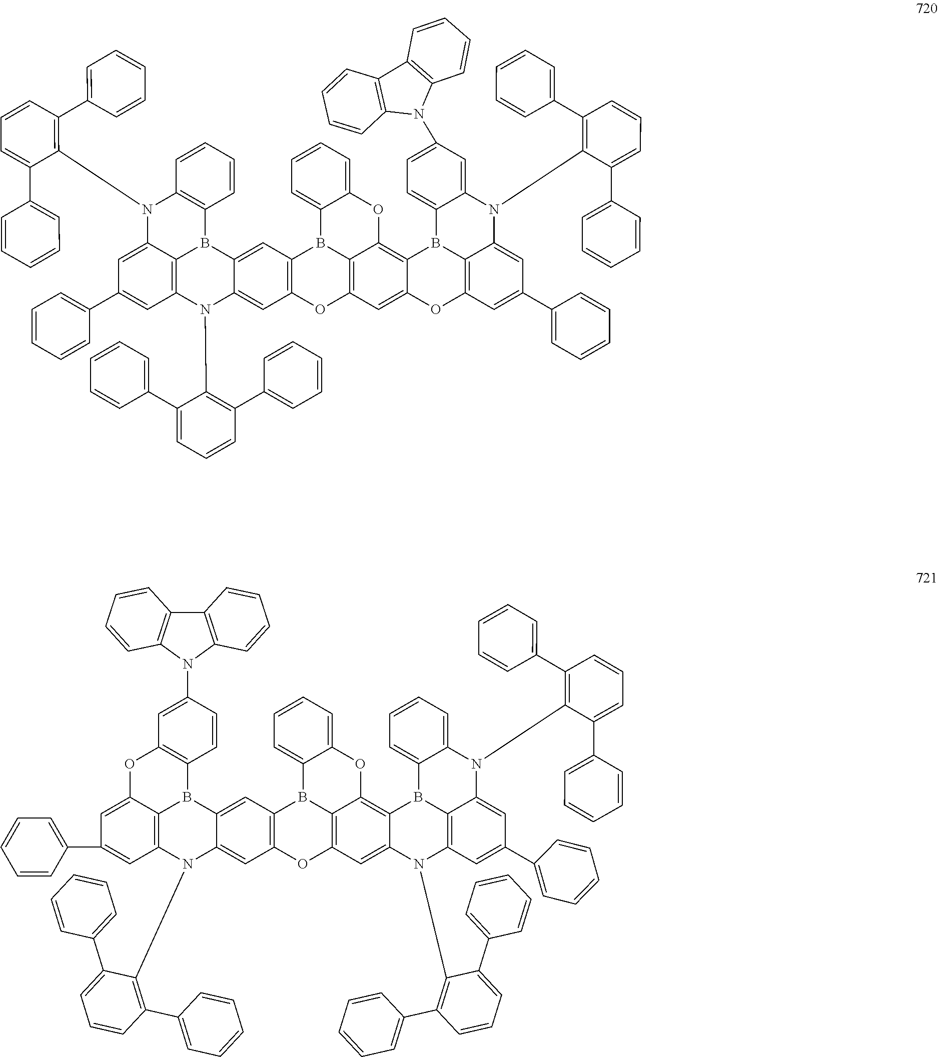 [SMILES: c1ccc(-c2cc3c4c(c2)N(c2c(-c5ccccc5)cccc2-c2ccccc2)c2cc(-n5c6ccccc6c6ccccc65)ccc2B4c2c(cc4c5c2Oc2ccccc2B5c2cc5c(cc2O4)N(c2c(-c4ccccc4)cccc2-c2ccccc2)c2cc(-c4ccccc4)cc4c2B5c2ccccc2N4c2c(-c4ccccc4)cccc2-c2ccccc2)O3)cc1 ; c1ccc(-c2cc3c4c(c2)N(c2c(-c5ccccc5)cccc2-c2ccccc2)c2cc5c(cc2B4c2ccc(-n4c6ccccc6c6ccccc64)cc2O3)B2c3ccccc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)O5)cc1] 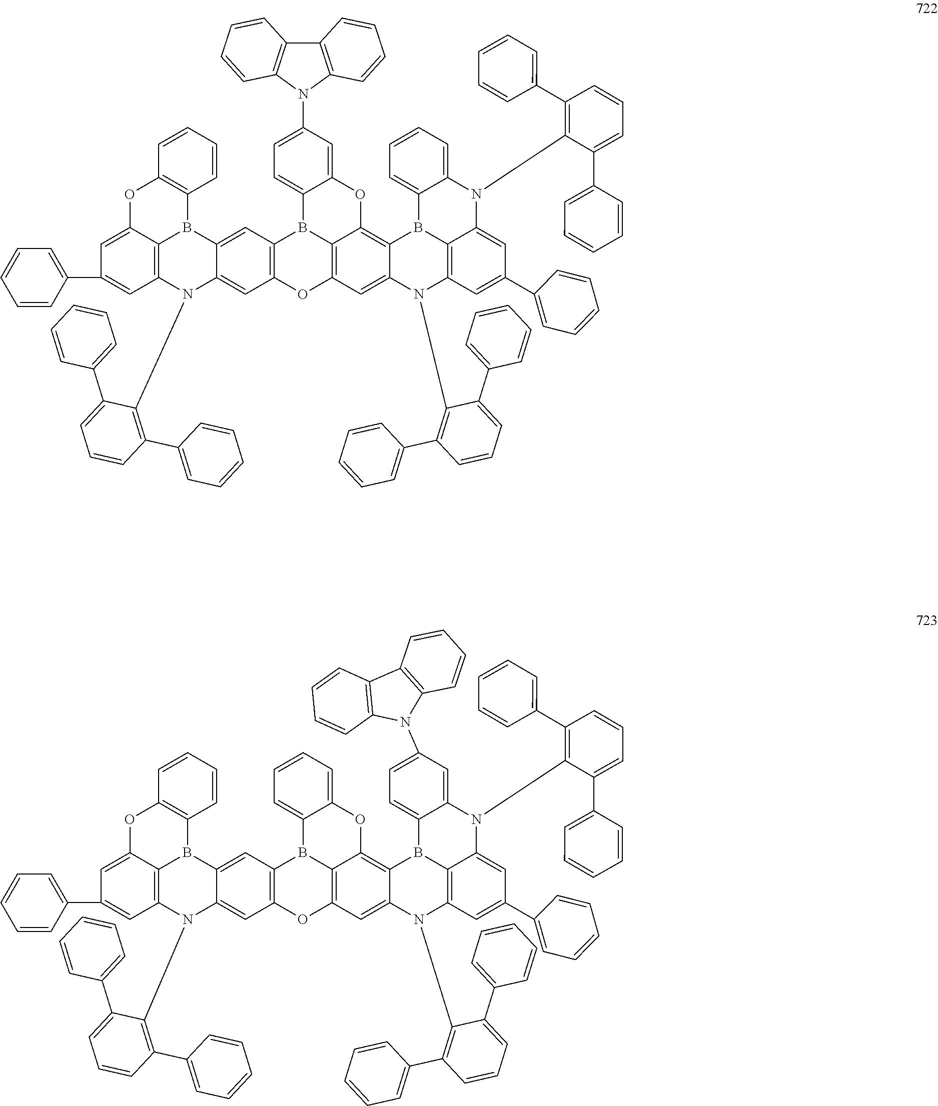 [SMILES: c1ccc(-c2cc3c4c(c2)N(c2c(-c5ccccc5)cccc2-c2ccccc2)c2cc5c(cc2B4c2ccccc2O3)B2c3ccc(-n4c6ccccc6c6ccccc64)cc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)O5)cc1 ; c1ccc(-c2cc3c4c(c2)N(c2c(-c5ccccc5)cccc2-c2ccccc2)c2cc5c(cc2B4c2ccccc2O3)B2c3ccccc3Oc3c2c(cc2c3B3c4ccc(-n6c7ccccc7c7ccccc76)cc4N(c4c(-c6ccccc6)cccc4-c4ccccc4)c4cc(-c6ccccc6)cc(c43)N2c2c(-c3ccccc3)cccc2-c2ccccc2)O5)cc1] 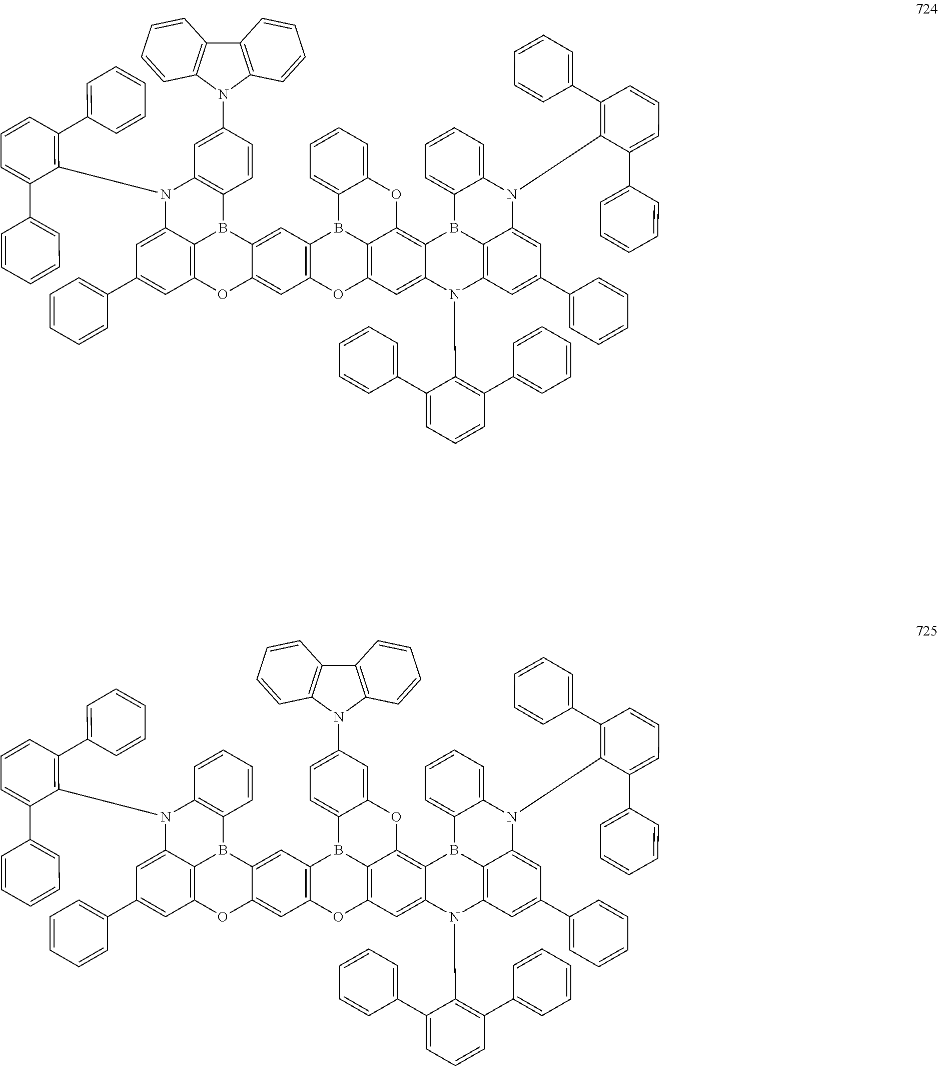 [SMILES: c1ccc(-c2cc3c4c(c2)N(c2c(-c5ccccc5)cccc2-c2ccccc2)c2cc(-n5c6ccccc6c6ccccc65)ccc2B4c2cc4c(cc2O3)Oc2cc3c(c5c2B4c2ccccc2O5)B2c4ccccc4N(c4c(-c5ccccc5)cccc4-c4ccccc4)c4cc(-c5ccccc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2ccccc2B4c2cc4c(cc2O3)Oc2cc3c(c5c2B4c2ccc(-n4c6ccccc6c6ccccc64)cc2O5)B2c4ccccc4N(c4c(-c5ccccc5)cccc4-c4ccccc4)c4cc(-c5ccccc5)cc(c42)N3c2c(-c3ccccc3)cccc2-c2ccccc2)cc1] 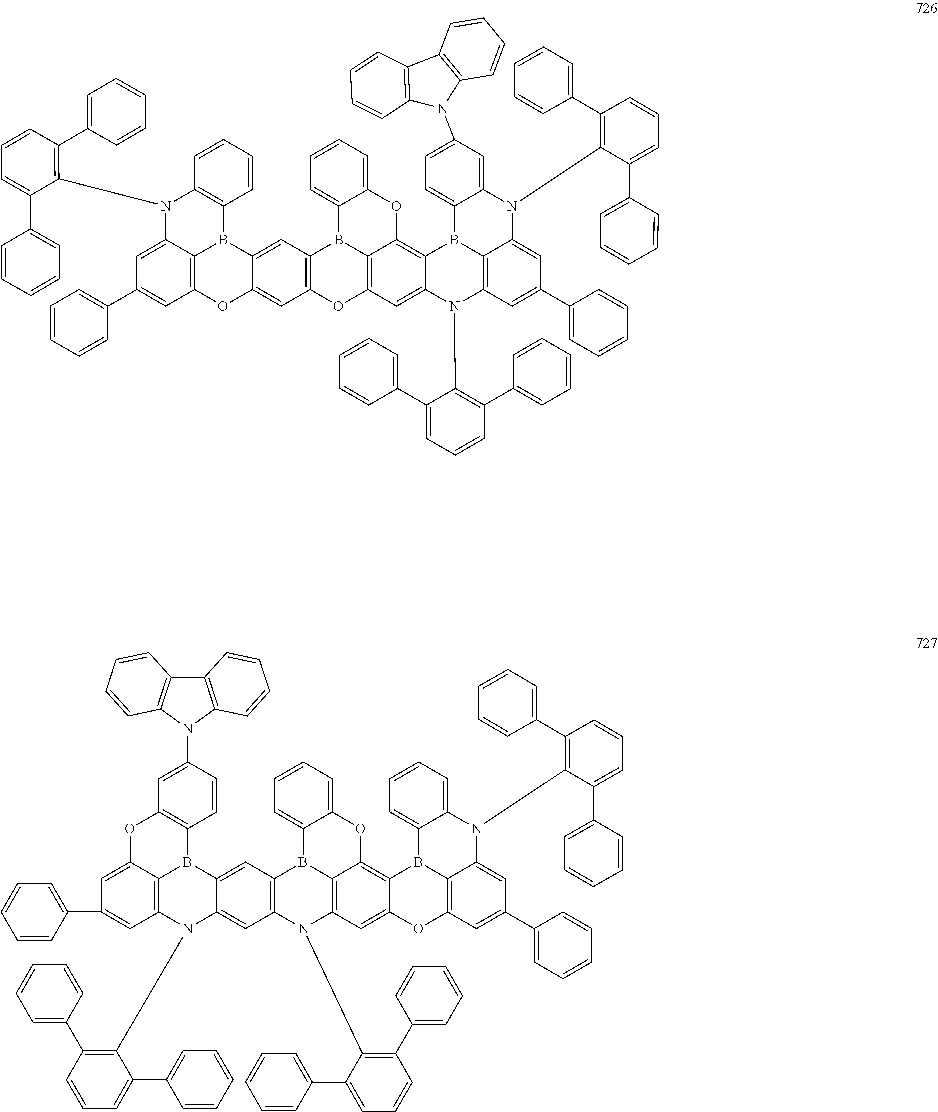 [SMILES: c1ccc(-c2cc3c4c(c2)N(c2c(-c5ccccc5)cccc2-c2ccccc2)c2ccccc2B4c2cc4c(cc2O3)Oc2cc3c(c5c2B4c2ccccc2O5)B2c4ccc(-n5c6ccccc6c6ccccc65)cc4N(c4c(-c5ccccc5)cccc4-c4ccccc4)c4cc(-c5ccccc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccc(-n4c6ccccc6c6ccccc64)cc2O3)B2c3ccccc3Oc3c4c(cc(c32)N5c2c(-c3ccccc3)cccc2-c2ccccc2)Oc2cc(-c3ccccc3)cc3c2B4c2ccccc2N3c2c(-c3ccccc3)cccc2-c2ccccc2)cc1] 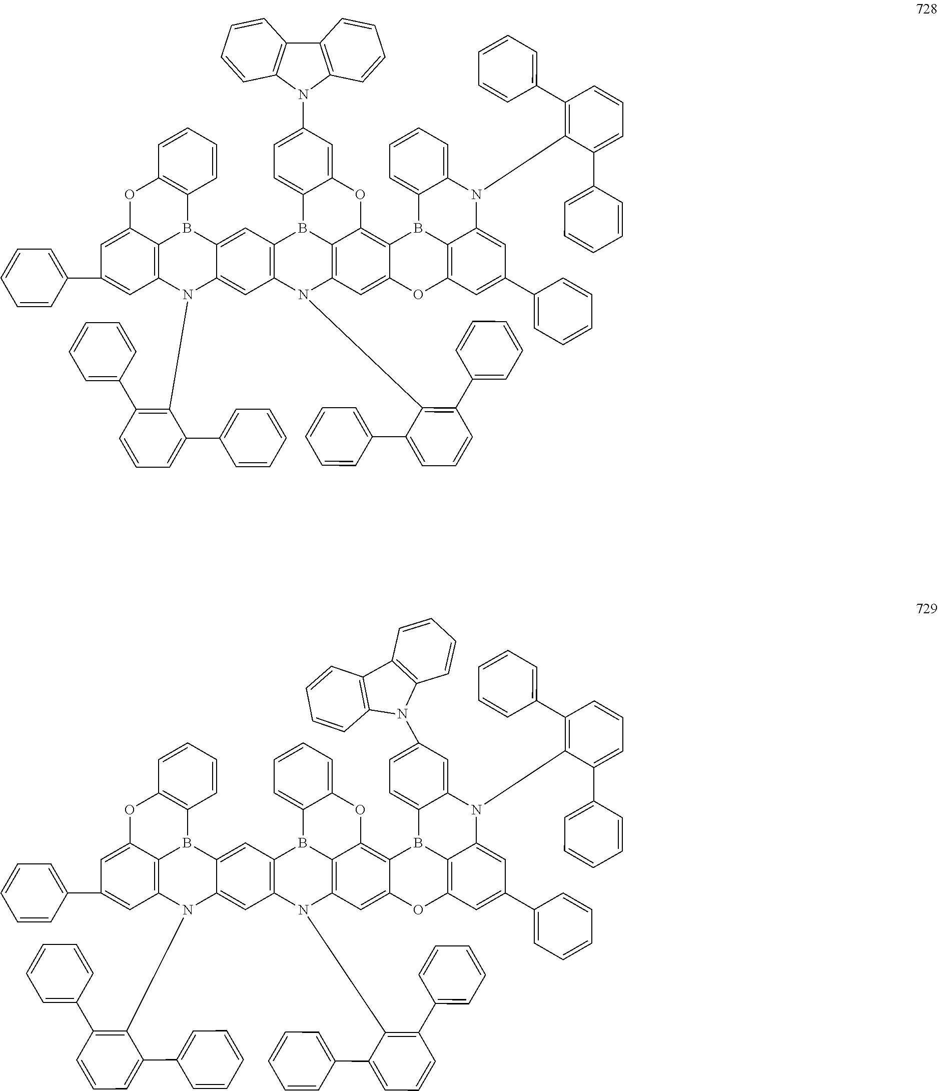 [SMILES: c1ccc(-c2cc3c4c(c2)N(c2c(-c5ccccc5)cccc2-c2ccccc2)c2cc5c(cc2B4c2ccccc2O3)B2c3ccc(-n4c6ccccc6c6ccccc64)cc3Oc3c4c(cc(c32)N5c2c(-c3ccccc3)cccc2-c2ccccc2)Oc2cc(-c3ccccc3)cc3c2B4c2ccccc2N3c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccccc2O3)B2c3ccccc3Oc3c4c(cc(c32)N5c2c(-c3ccccc3)cccc2-c2ccccc2)Oc2cc(-c3ccccc3)cc3c2B4c2ccc(-n4c5ccccc5c5ccccc54)cc2N3c2c(-c3ccccc3)cccc2-c2ccccc2)cc1] 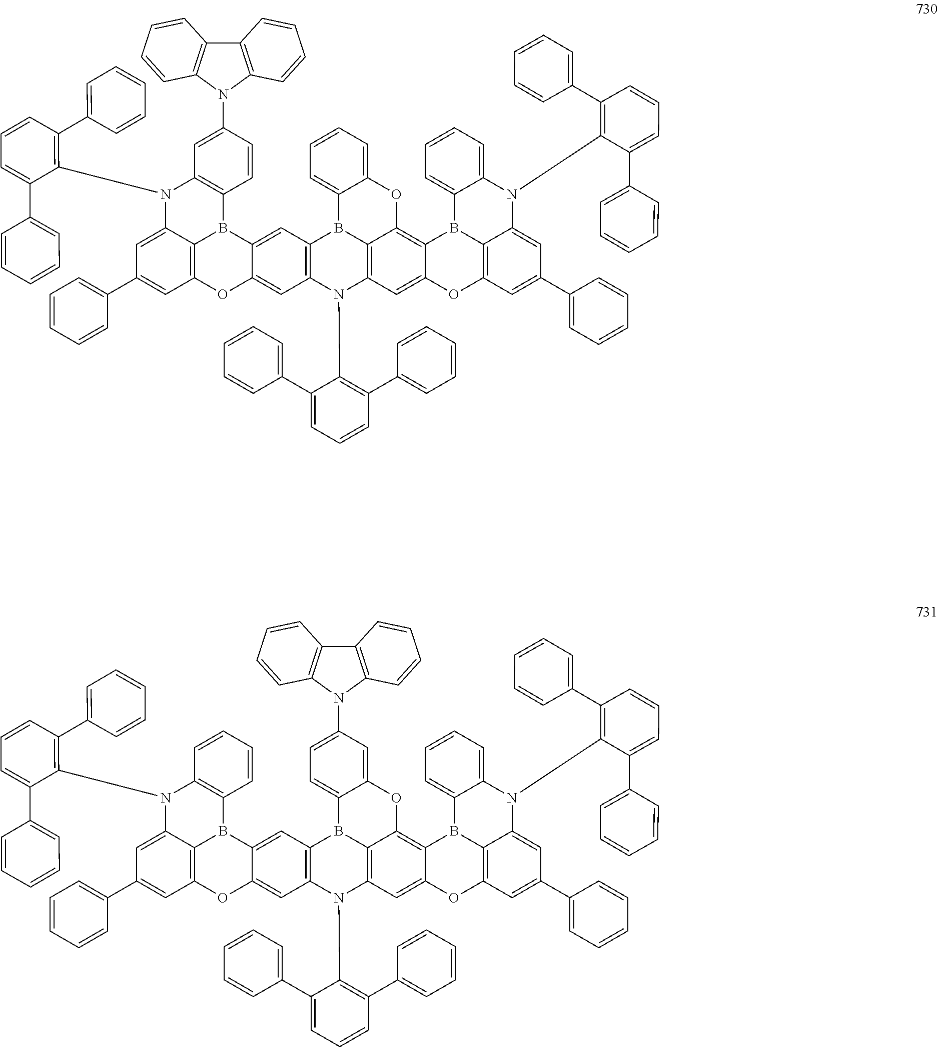 [SMILES: c1ccc(-c2cc3c4c(c2)N(c2c(-c5ccccc5)cccc2-c2ccccc2)c2cc(-n5c6ccccc6c6ccccc65)ccc2B4c2cc4c(cc2O3)N(c2c(-c3ccccc3)cccc2-c2ccccc2)c2cc3c(c5c2B4c2ccccc2O5)B2c4ccccc4N(c4c(-c5ccccc5)cccc4-c4ccccc4)c4cc(-c5ccccc5)cc(c42)O3)cc1 ; c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc3c(c5c2B4c2ccc(-n4c6ccccc6c6ccccc64)cc2O5)B2c4ccccc4N(c4c(-c5ccccc5)cccc4-c4ccccc4)c4cc(-c5ccccc5)cc(c42)O3)cc1] 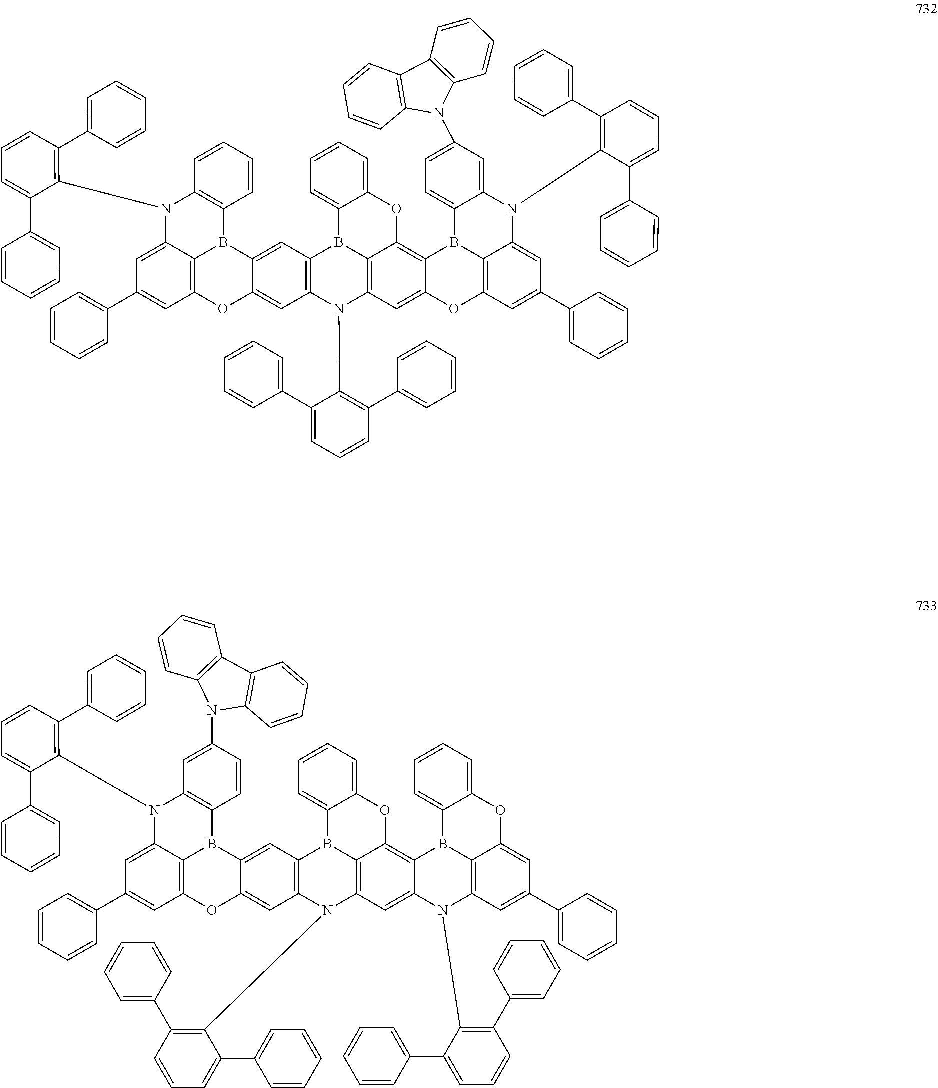 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc3c(c5c2B4c2ccccc2O5)B2c4ccc(-n5c6ccccc6c6ccccc65)cc4N(c4c(-c5ccccc5)cccc4-c4ccccc4)c4cc(-c5ccccc5)cc(c42)O3)cc1 ; c1ccc(-c2cc3c4c(c2)N(c2c(-c5ccccc5)cccc2-c2ccccc2)c2cc(-n5c6ccccc6c6ccccc65)ccc2B4c2cc4c(cc2O3)N(c2c(-c3ccccc3)cccc2-c2ccccc2)c2cc3c(c5c2B4c2ccccc2O5)B2c4ccccc4Oc4cc(-c5ccccc5)cc(c42)N3c2c(-c3ccccc3)cccc2-c2ccccc2)cc1] 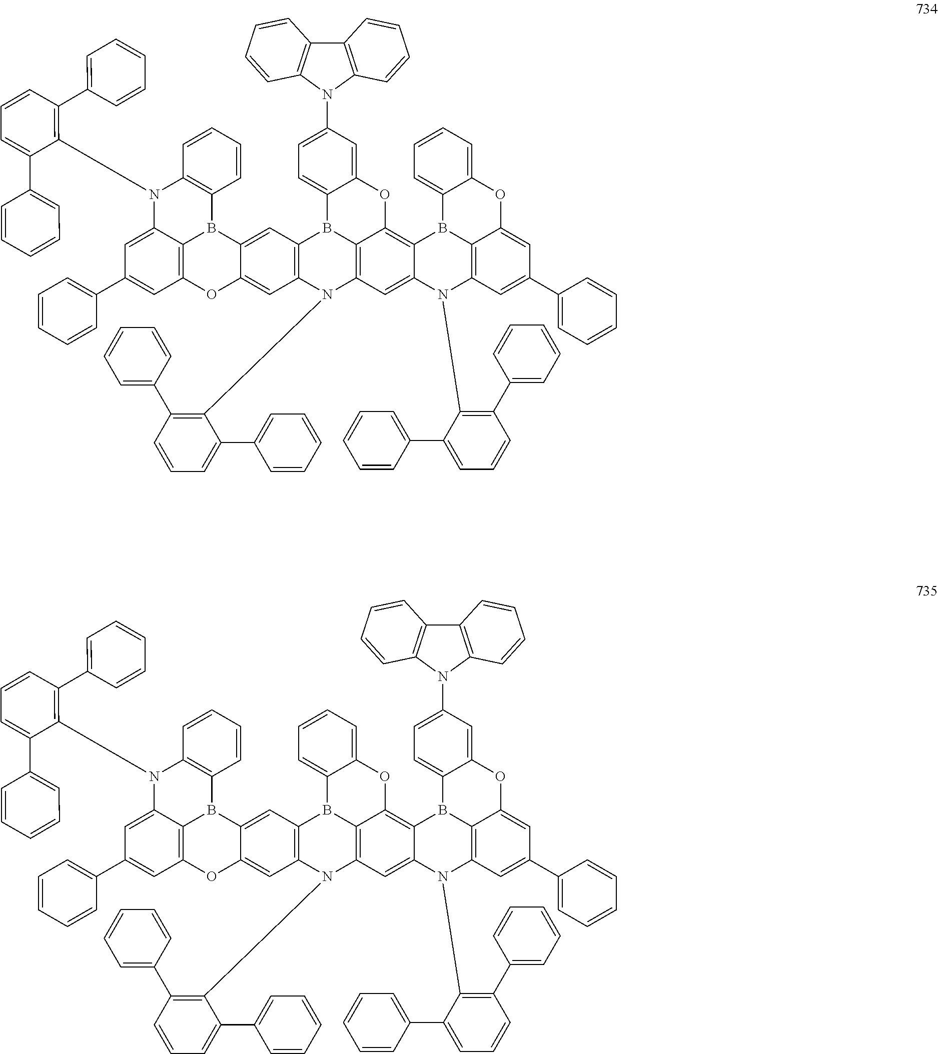 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc3c(c5c2B4c2ccc(-n4c6ccccc6c6ccccc64)cc2O5)B2c4ccccc4Oc4cc(-c5ccccc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc3c(c5c2B4c2ccccc2O5)B2c4ccc(-n5c6ccccc6c6ccccc65)cc4Oc4cc(-c5ccccc5)cc(c42)N3c2c(-c3ccccc3)cccc2-c2ccccc2)cc1] 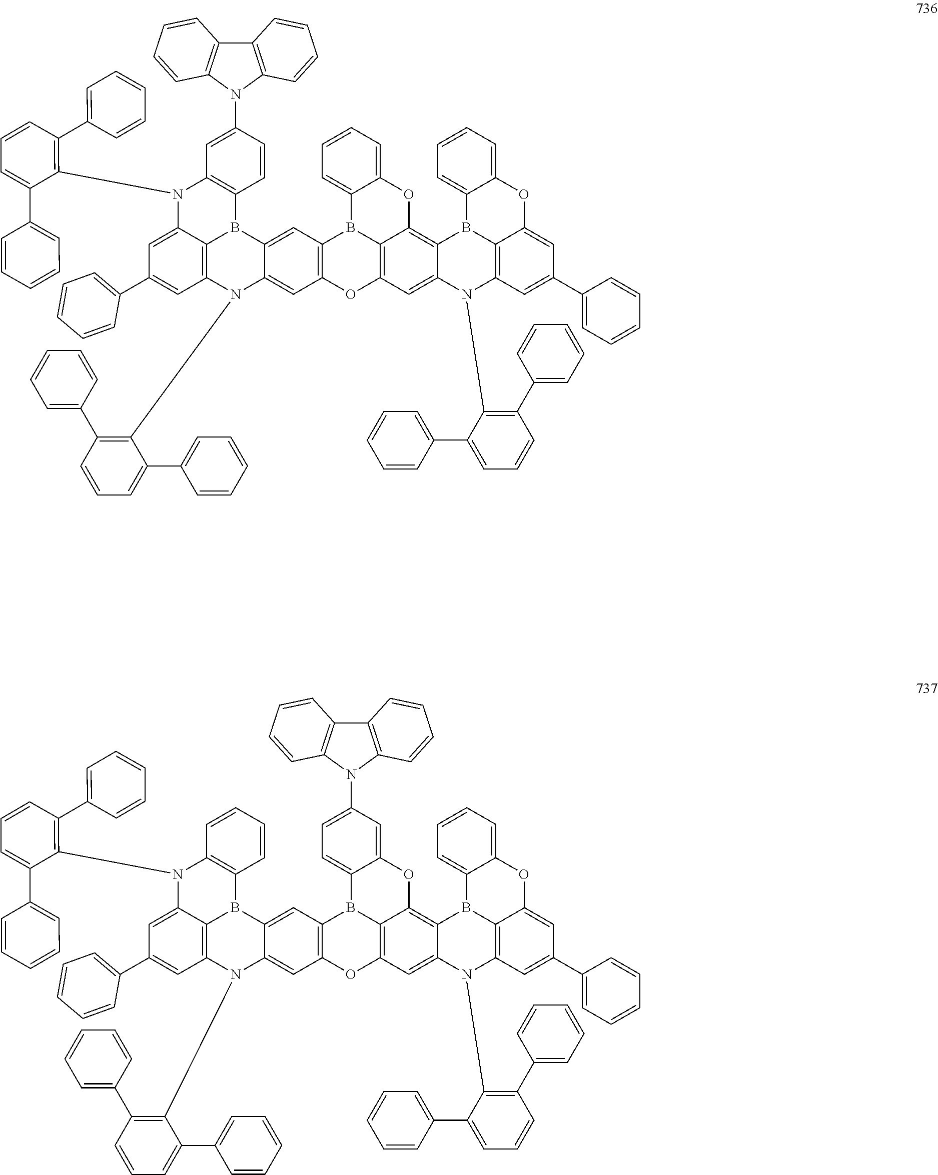 [SMILES: c1ccc(-c2cc3c4c(c2)N(c2c(-c5ccccc5)cccc2-c2ccccc2)c2cc5c6c(c2B4c2ccccc2O3)Oc2ccccc2B6c2cc3c(cc2O5)N(c2c(-c4ccccc4)cccc2-c2ccccc2)c2cc(-c4ccccc4)cc4c2B3c2ccc(-n3c5ccccc5c5ccccc53)cc2N4c2c(-c3ccccc3)cccc2-c2ccccc2)cc1 ; c1ccc(-c2cc3c4c(c2)N(c2c(-c5ccccc5)cccc2-c2ccccc2)c2cc5c6c(c2B4c2ccccc2O3)Oc2cc(-n3c4ccccc4c4ccccc43)ccc2B6c2cc3c(cc2O5)N(c2c(-c4ccccc4)cccc2-c2ccccc2)c2cc(-c4ccccc4)cc4c2B3c2ccccc2N4c2c(-c3ccccc3)cccc2-c2ccccc2)cc1] 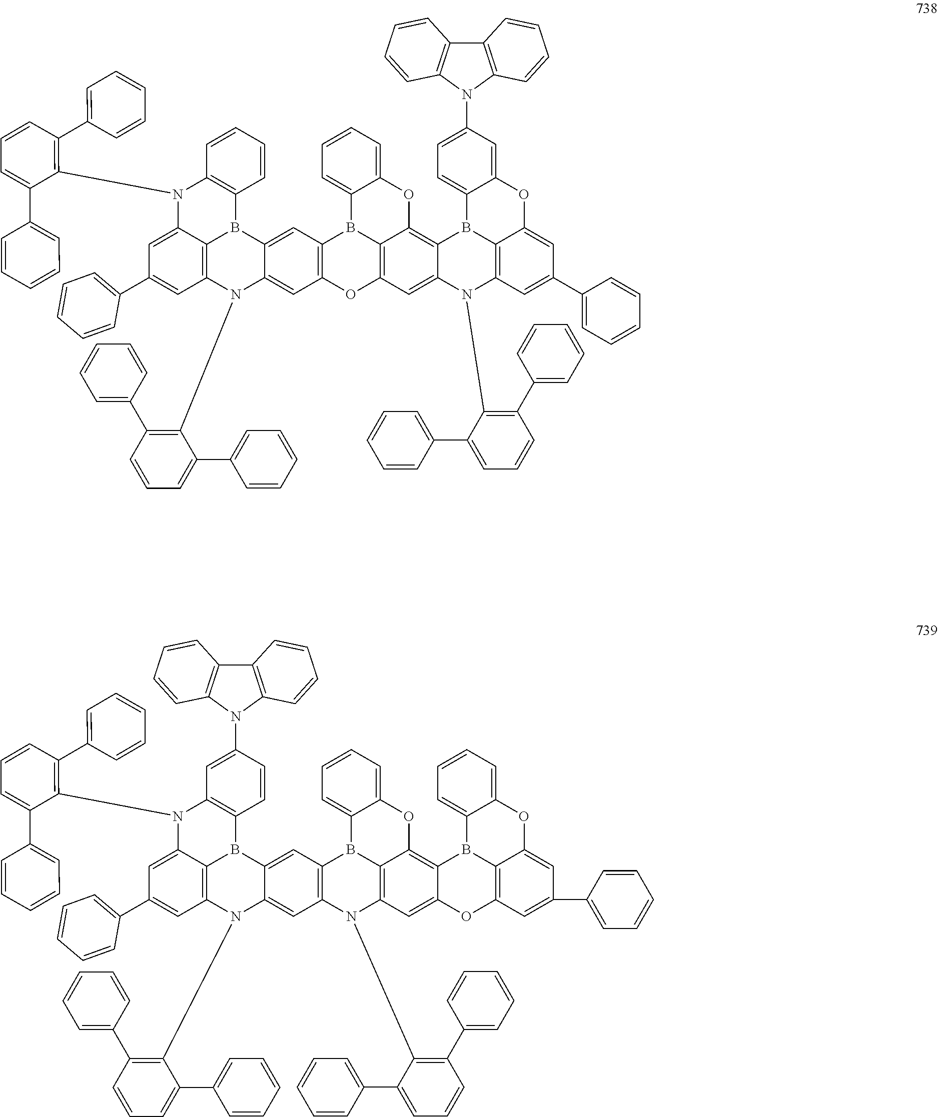 [SMILES: c1ccc(-c2cc3c4c(c2)N(c2c(-c5ccccc5)cccc2-c2ccccc2)c2cc5c6c(c2B4c2ccc(-n4c7ccccc7c7ccccc74)cc2O3)Oc2ccccc2B6c2cc3c(cc2O5)N(c2c(-c4ccccc4)cccc2-c2ccccc2)c2cc(-c4ccccc4)cc4c2B3c2ccccc2N4c2c(-c3ccccc3)cccc2-c2ccccc2)cc1 ; c1ccc(-c2cc3c4c(c2)Oc2cc5c6c(c2B4c2ccccc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccc(-n3c5ccccc5c5ccccc53)cc2N4c2c(-c3ccccc3)cccc2-c2ccccc2)cc1] 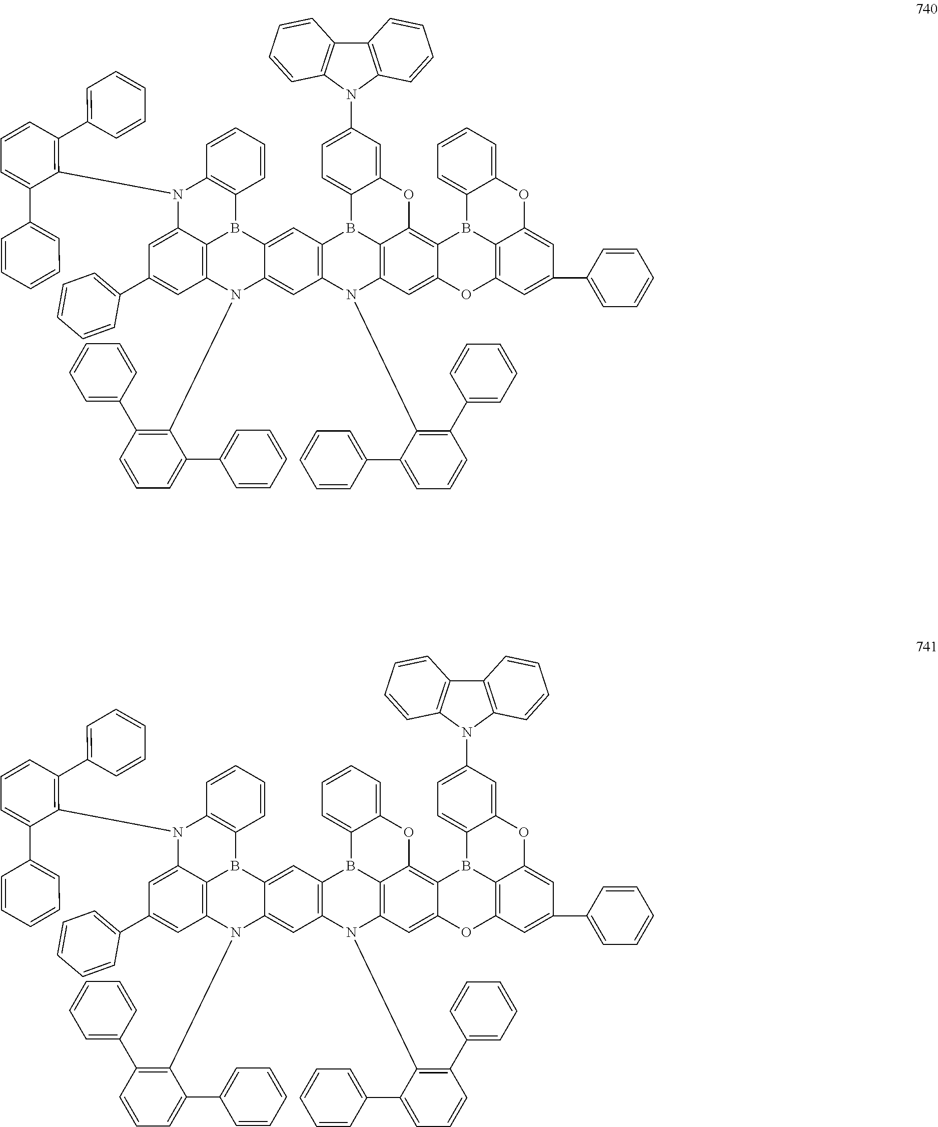 [SMILES: c1ccc(-c2cc3c4c(c2)Oc2cc5c6c(c2B4c2ccccc2O3)Oc2cc(-n3c4ccccc4c4ccccc43)ccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccccc2N4c2c(-c3ccccc3)cccc2-c2ccccc2)cc1 ; c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccccc2N4c2c(-c3ccccc3)cccc2-c2ccccc2)cc1] 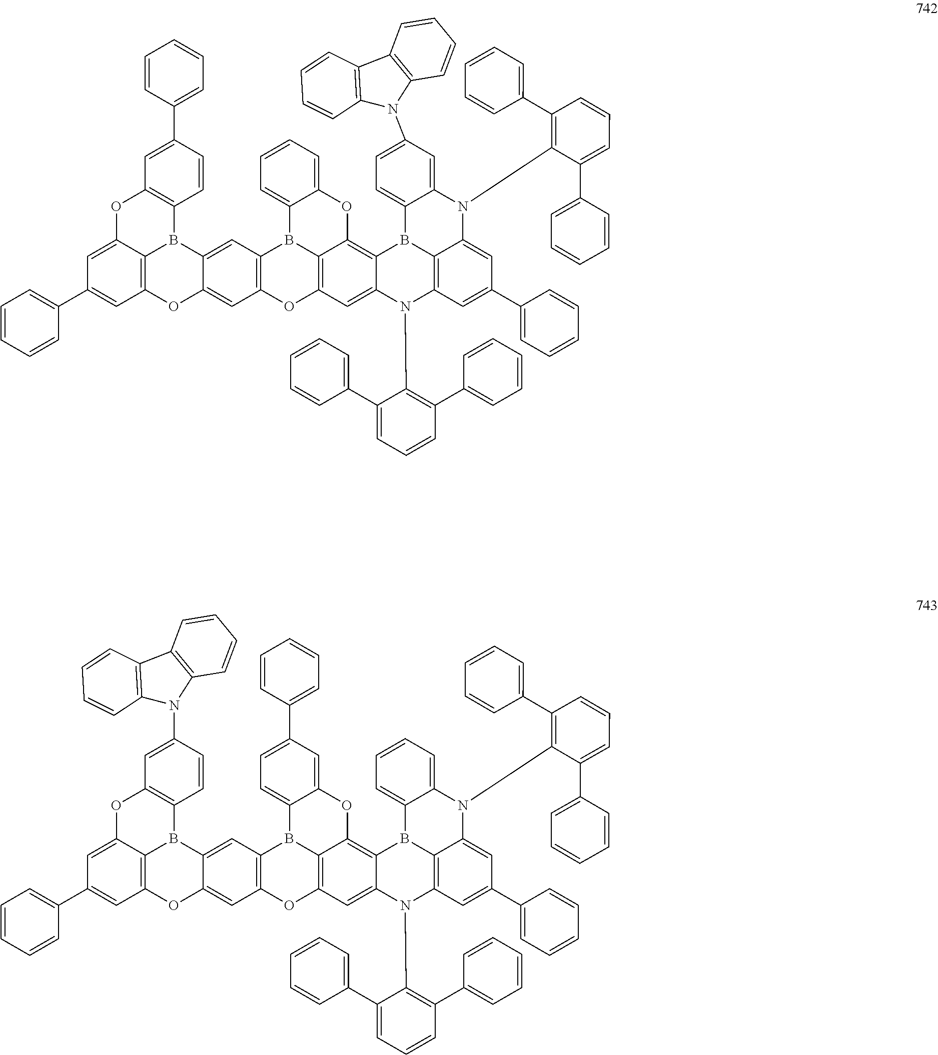 [SMILES: c1ccc(-c2ccc3c(c2)Oc2cc(-c4ccccc4)cc4c2B3c2cc3c(cc2O4)Oc2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3Oc3cc(-c4ccccc4)cc(c32)O5)cc1] 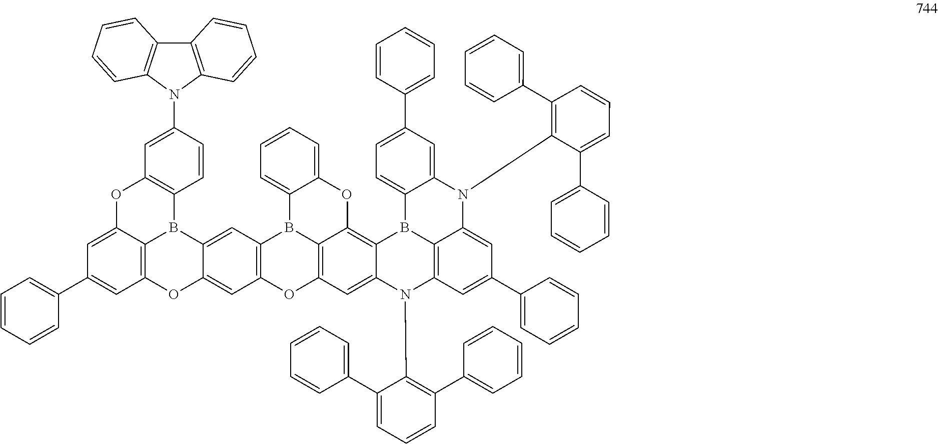 [SMILES: c1ccc(-c2cc3c4c(c2)Oc2cc5c(cc2B4c2ccc(-n4c6ccccc6c6ccccc64)cc2O3)B2c3ccccc3Oc3c2c(cc2c3B3c4ccc(-c6ccccc6)cc4N(c4c(-c6ccccc6)cccc4-c4ccccc4)c4cc(-c6ccccc6)cc(c43)N2c2c(-c3ccccc3)cccc2-c2ccccc2)O5)cc1] 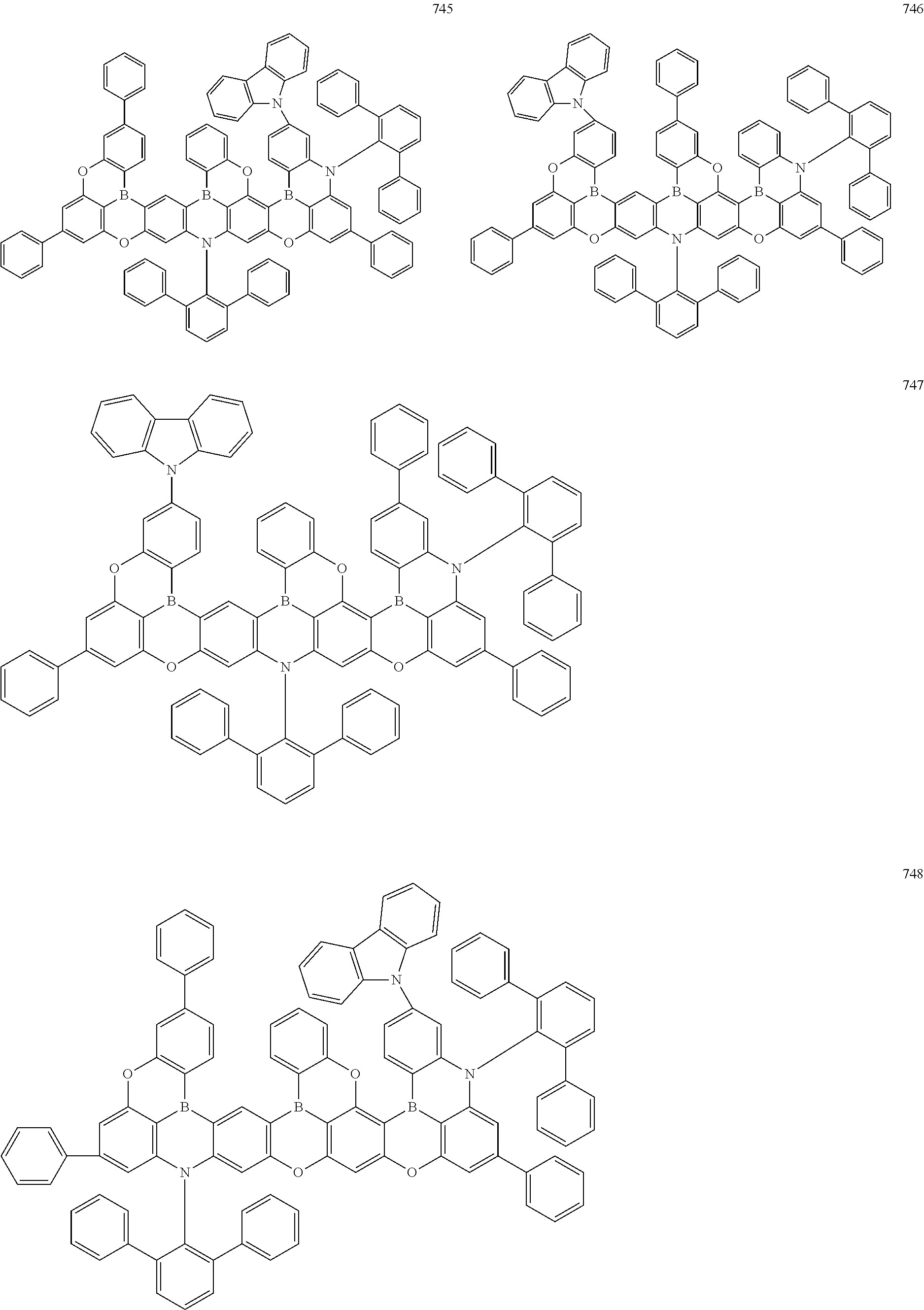 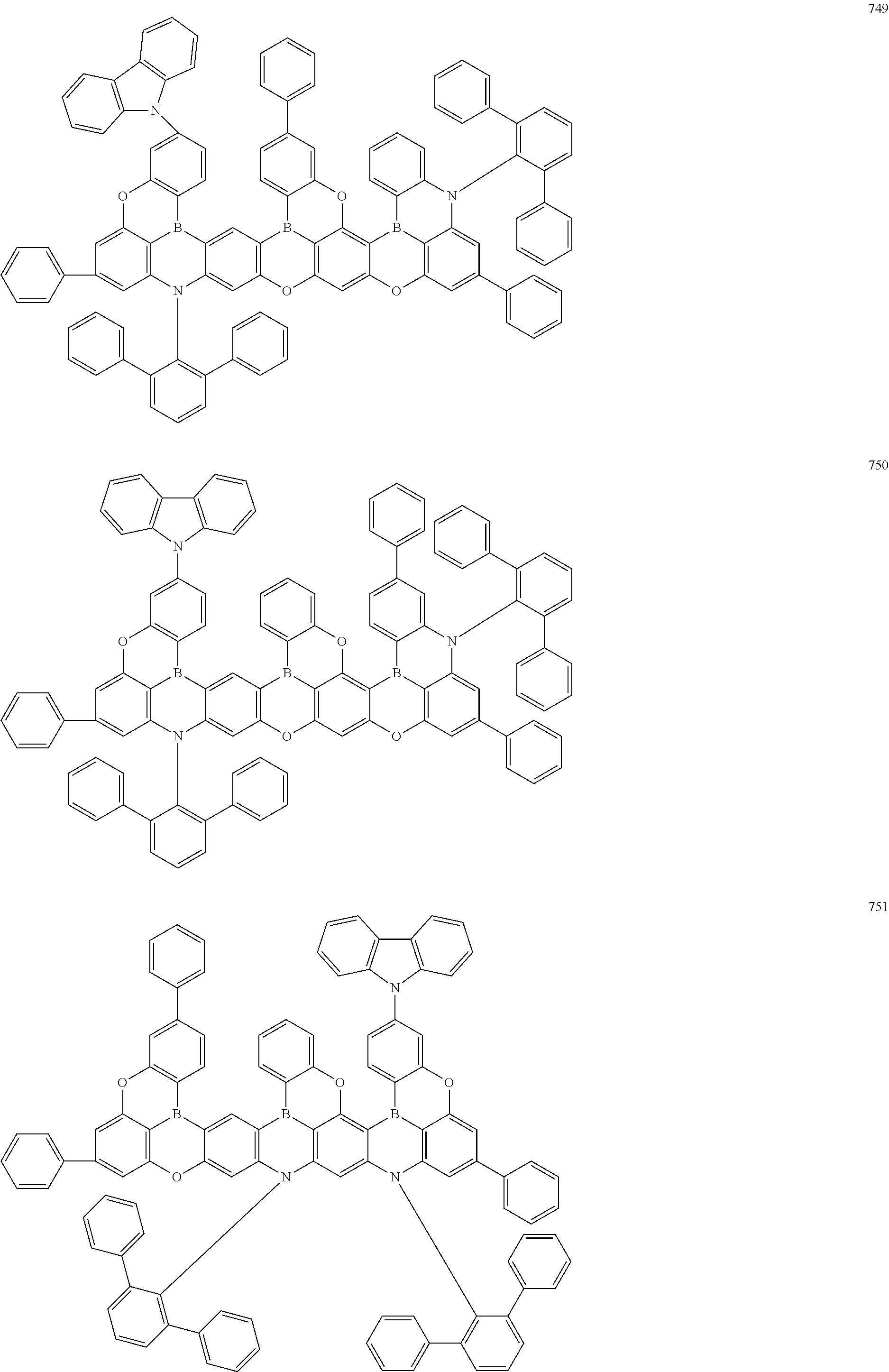 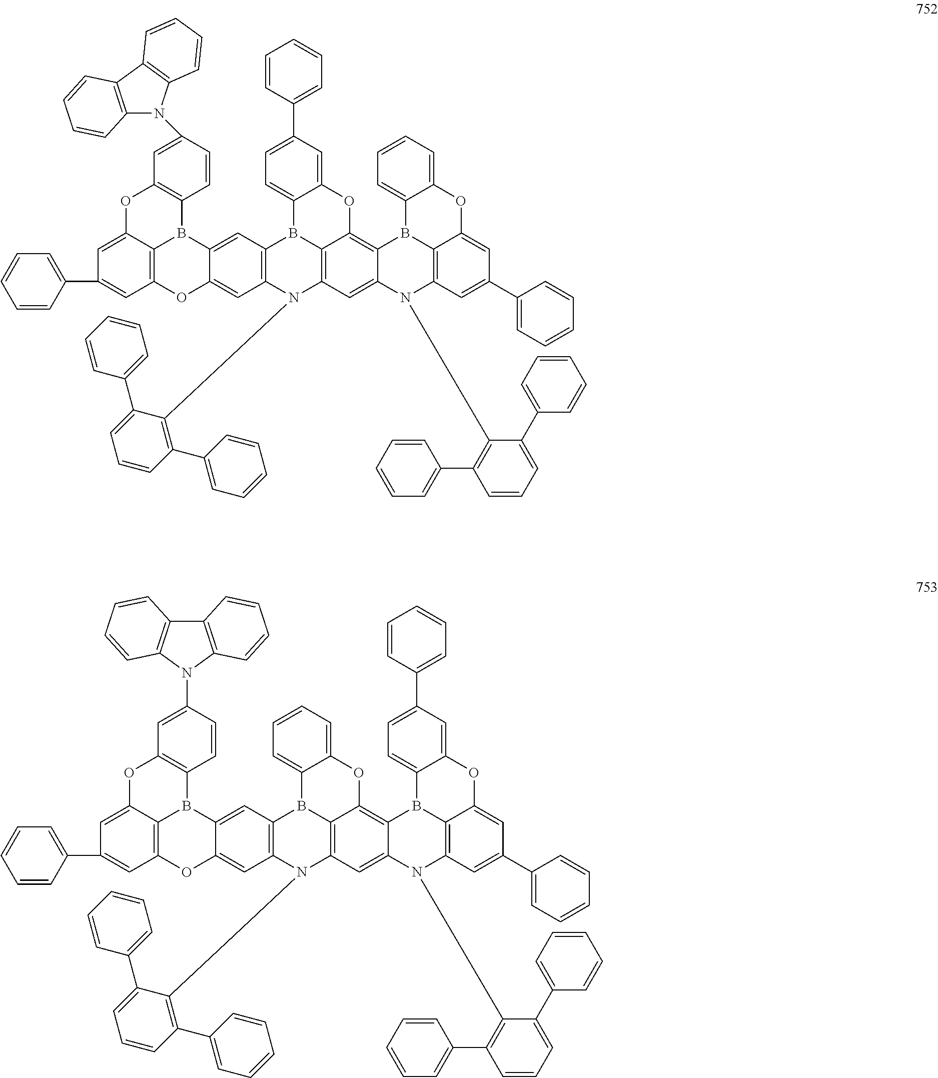 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3Oc3cc(-c4ccccc4)cc(c32)O5)cc1 ; c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2O3)N4c2c(-c3ccccc3)cccc2-c2ccccc2)cc1] 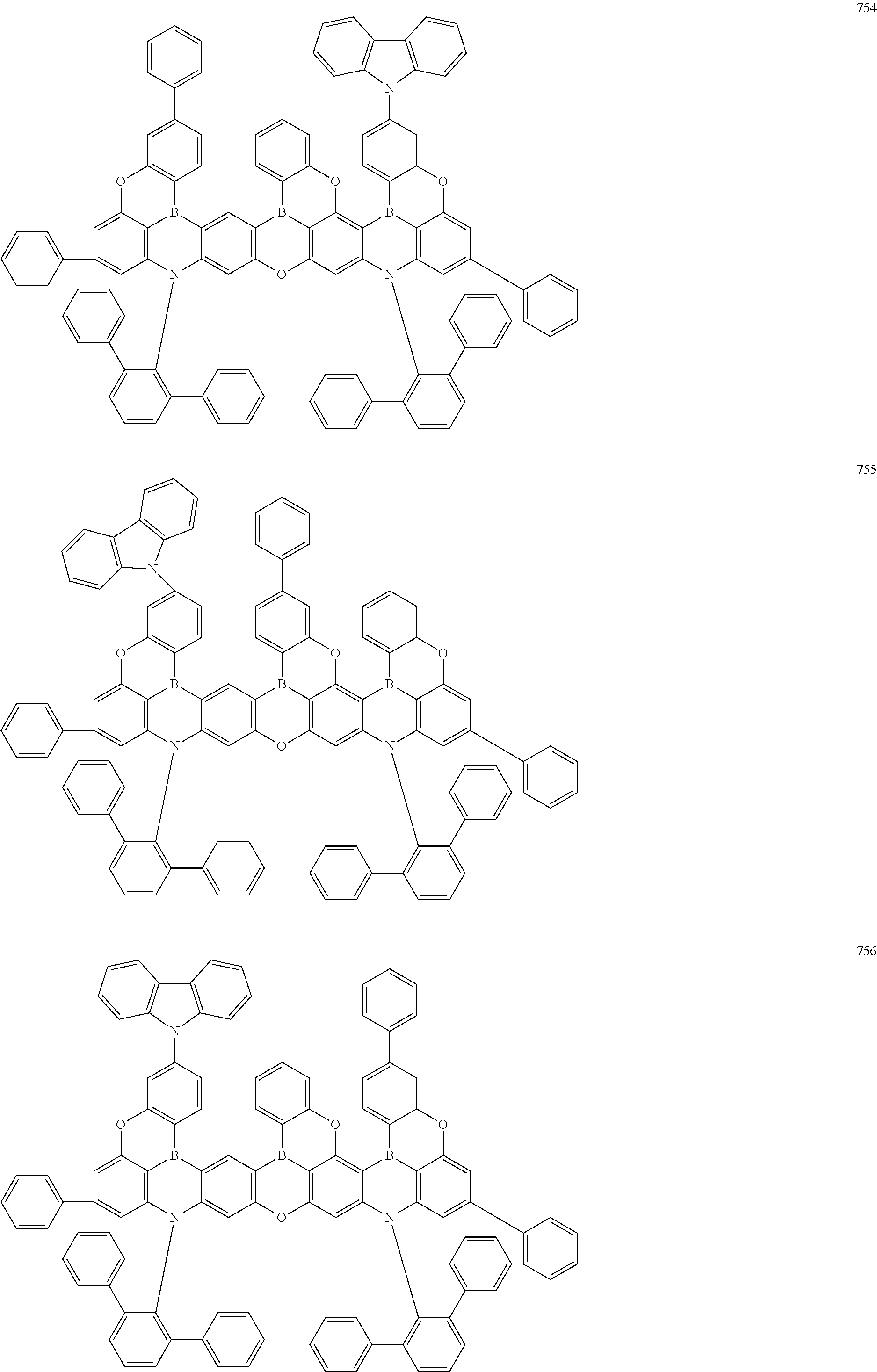 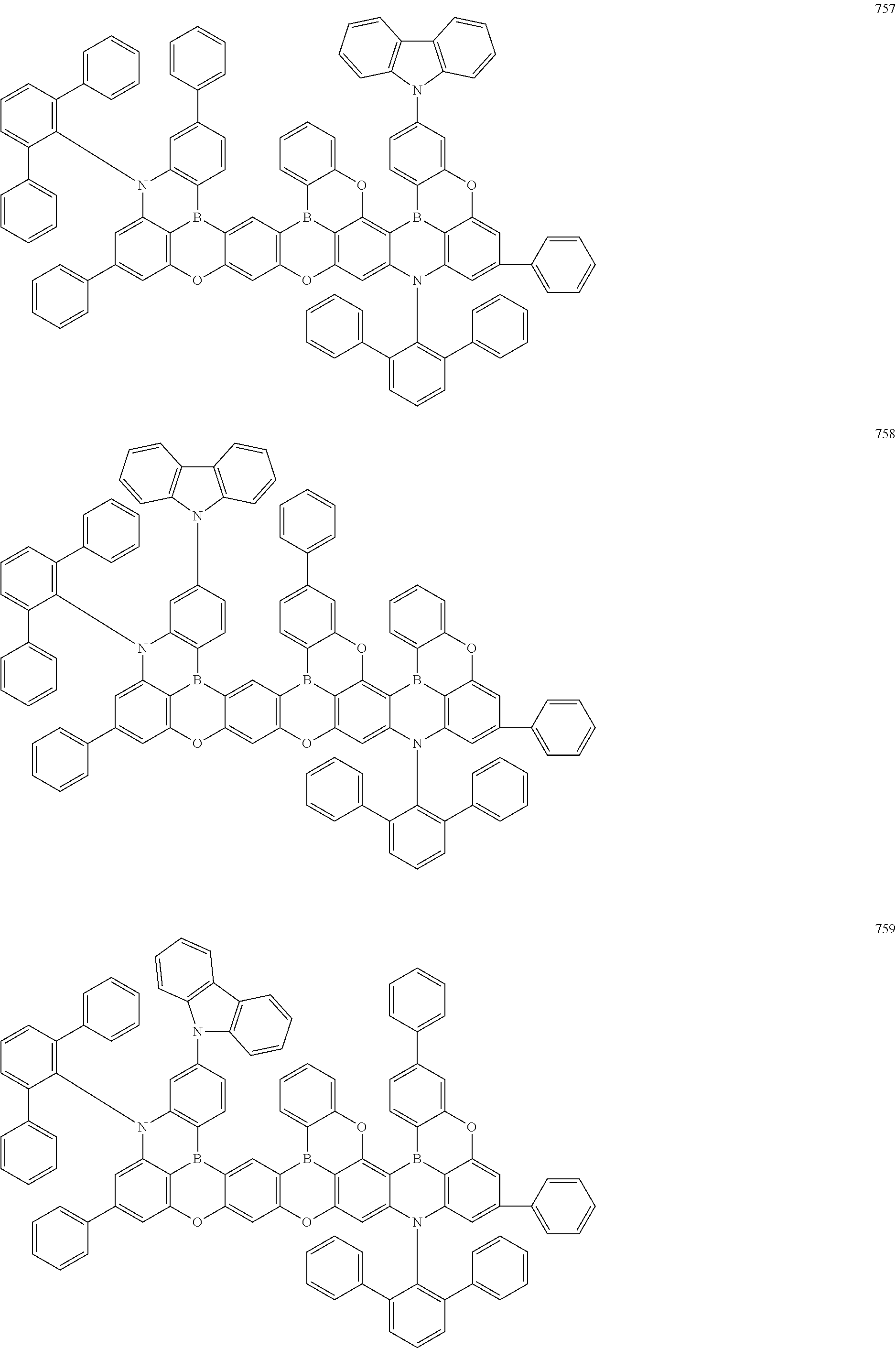 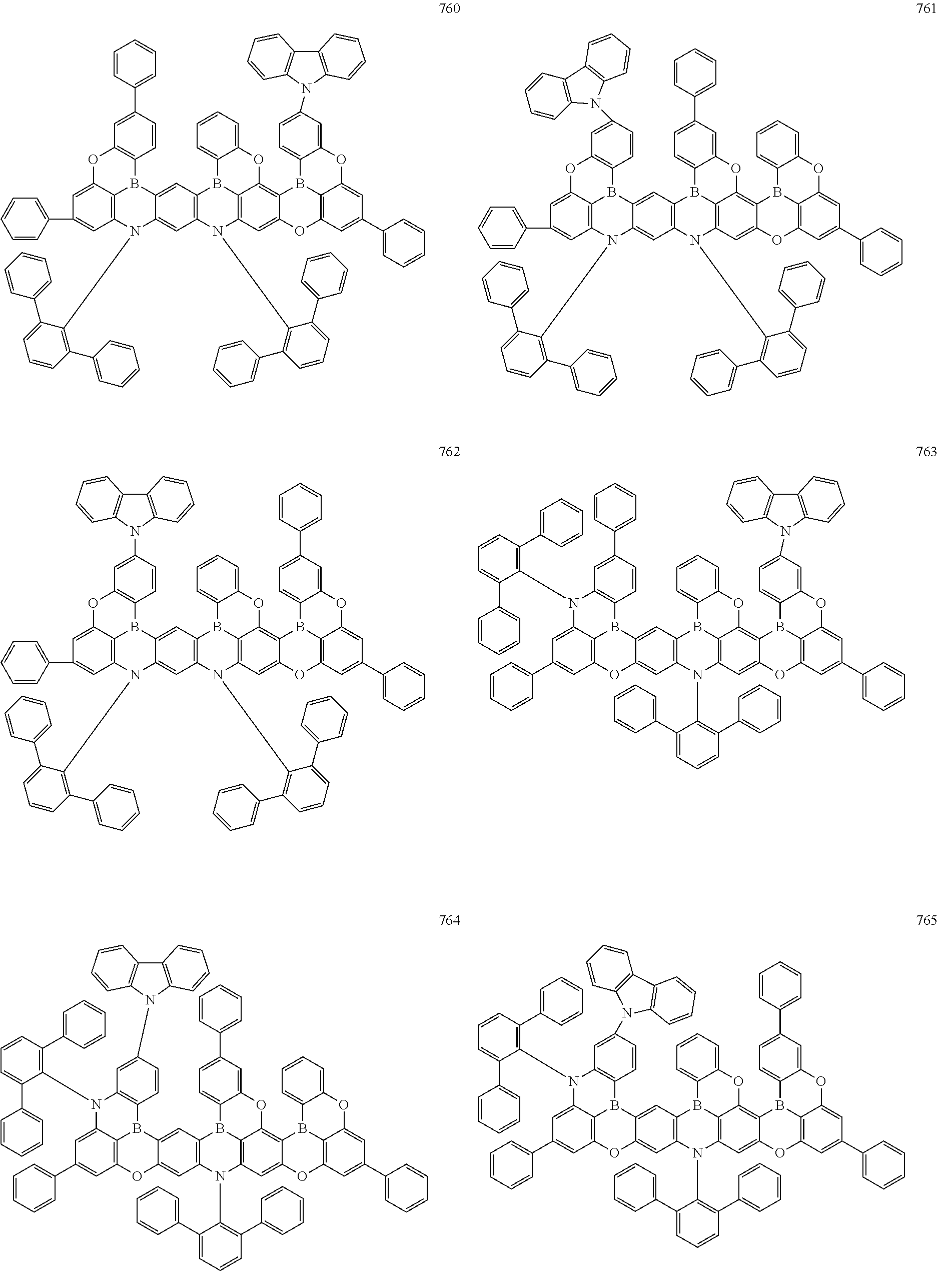 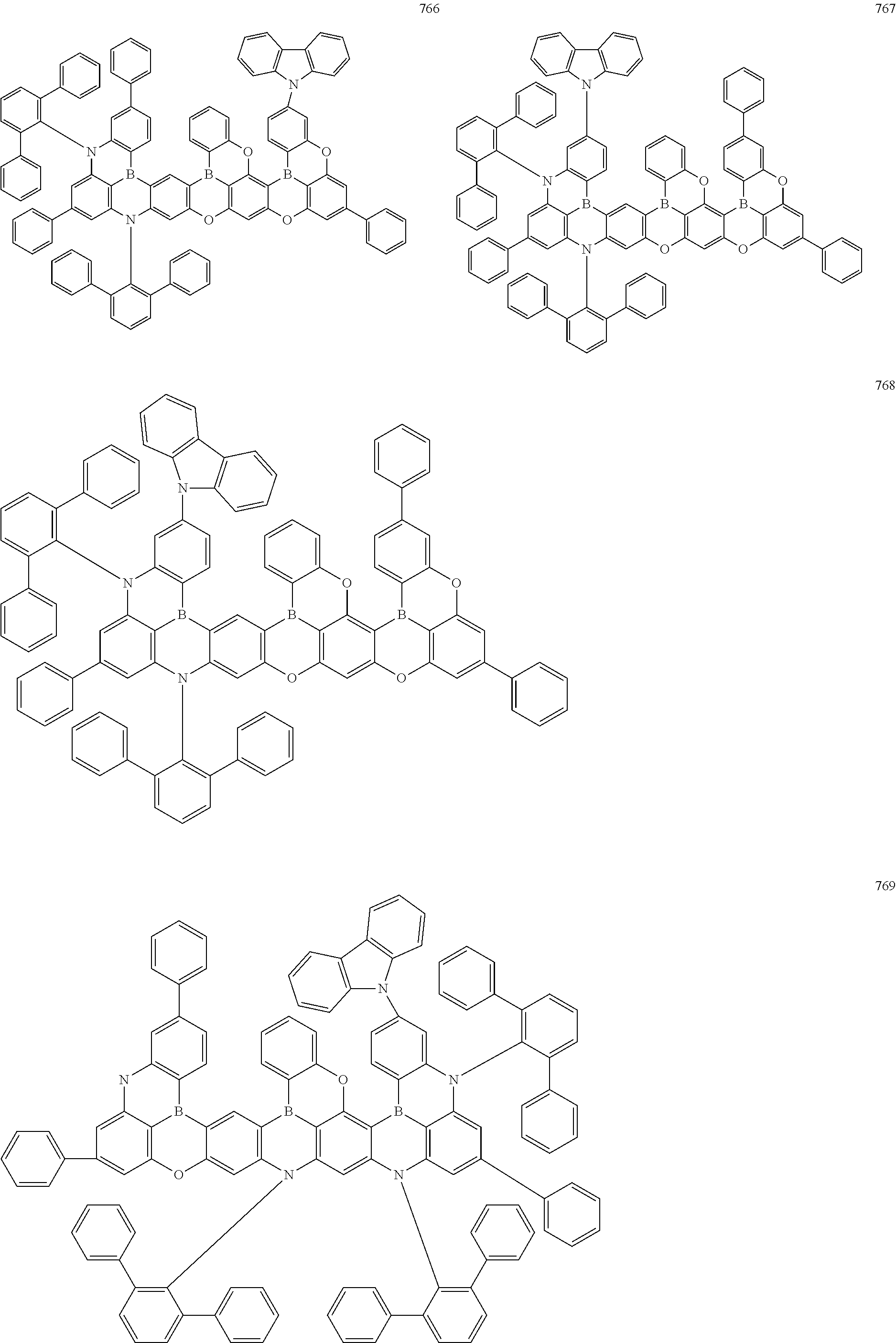 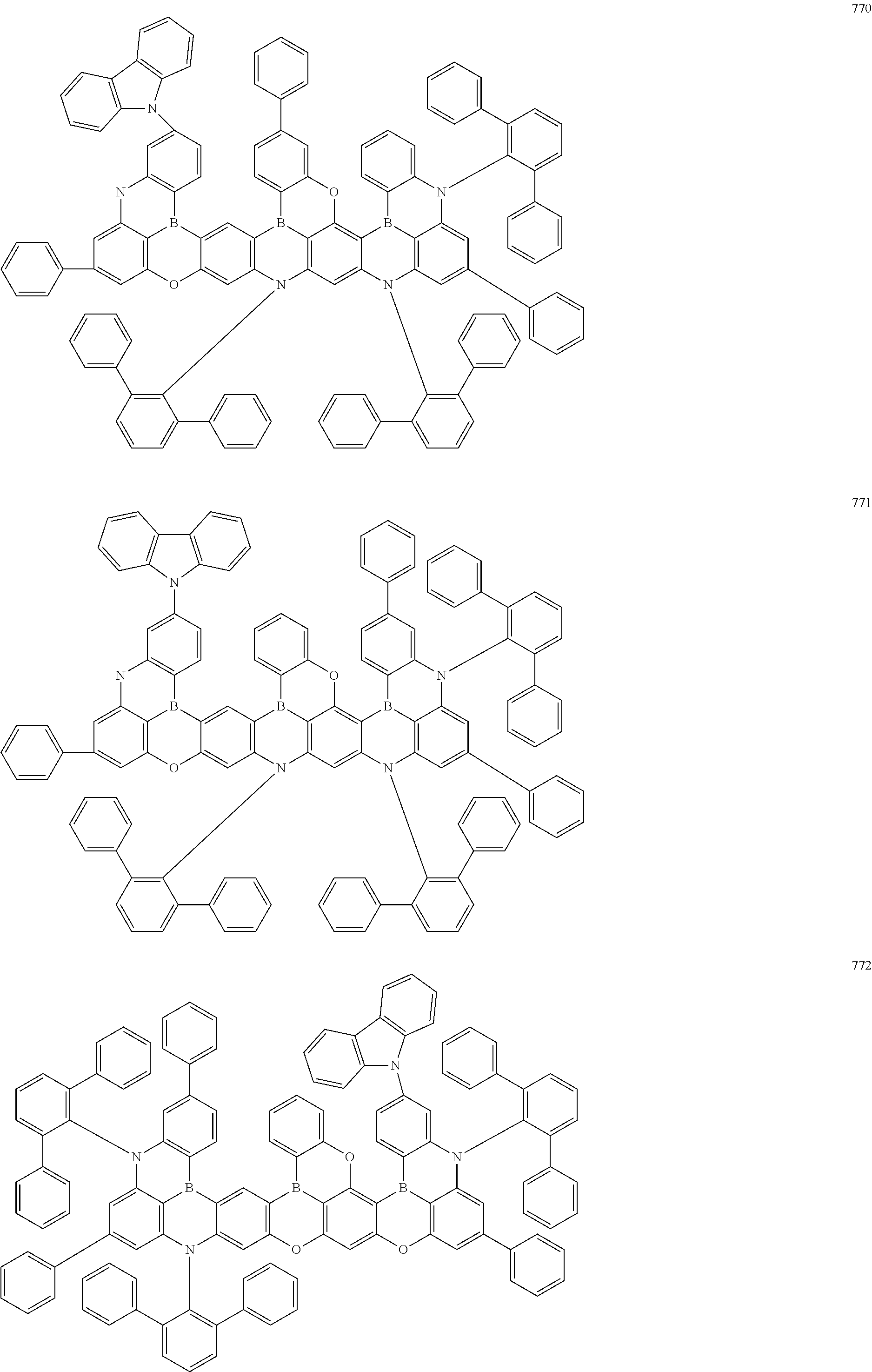 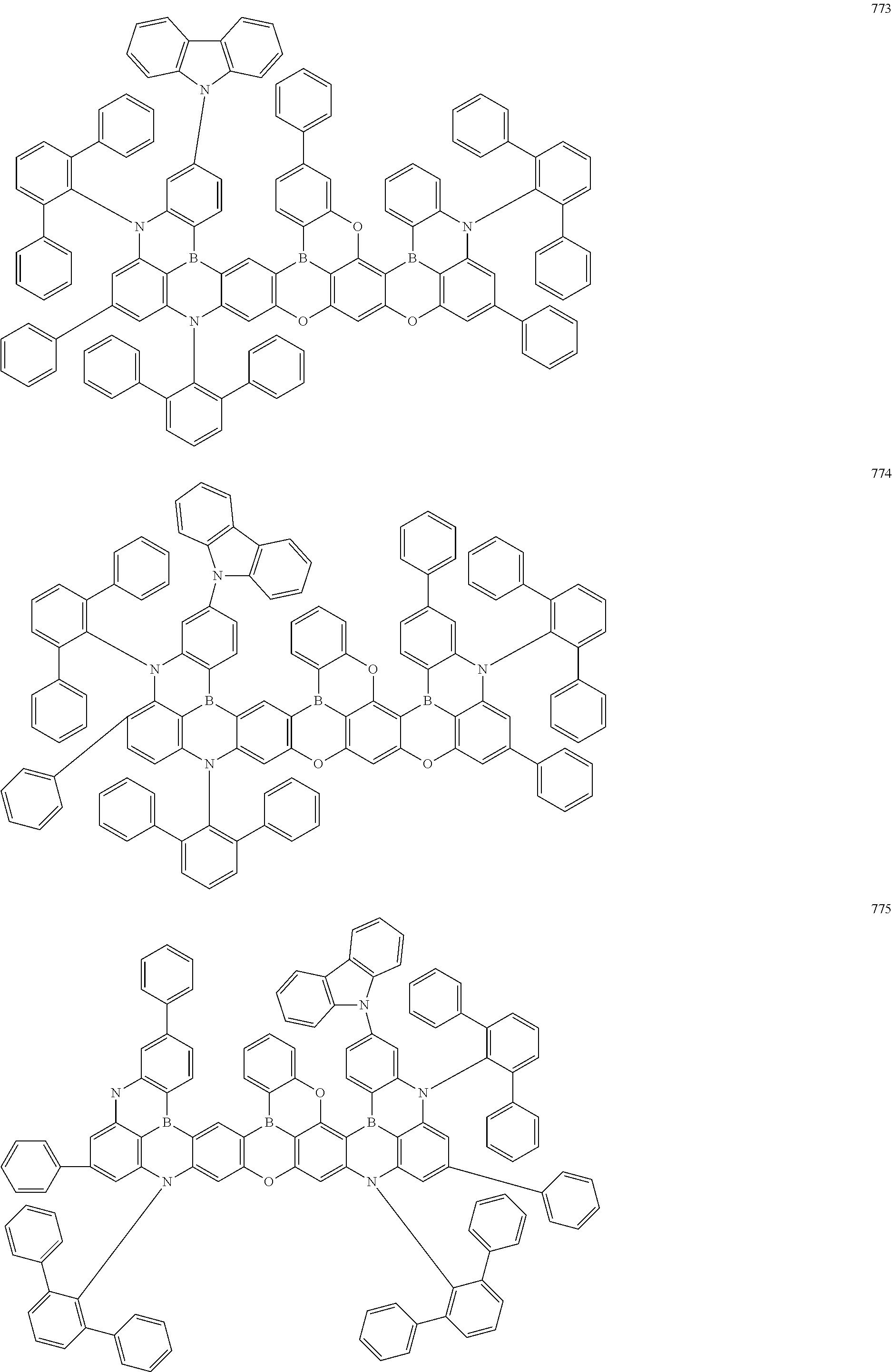 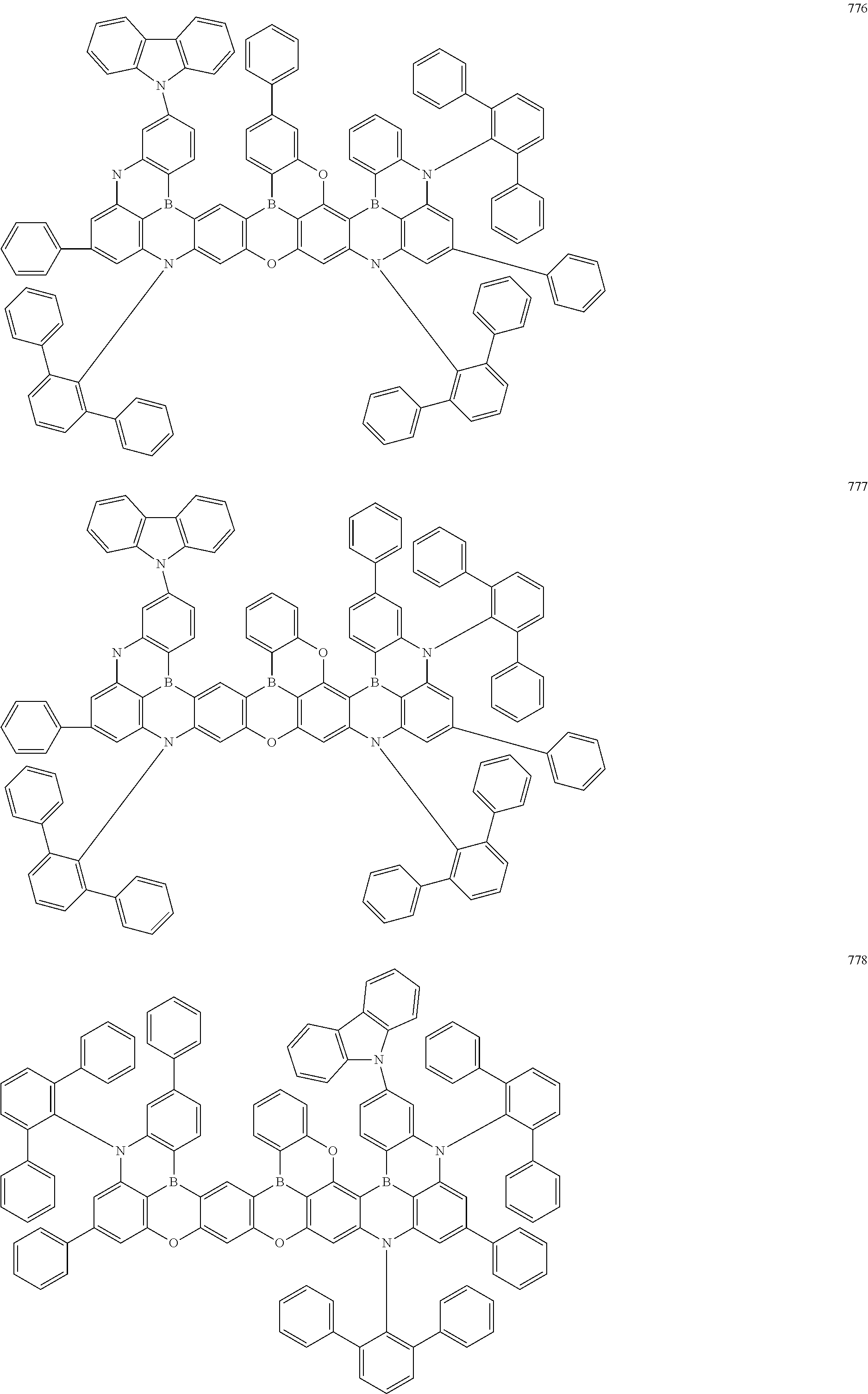 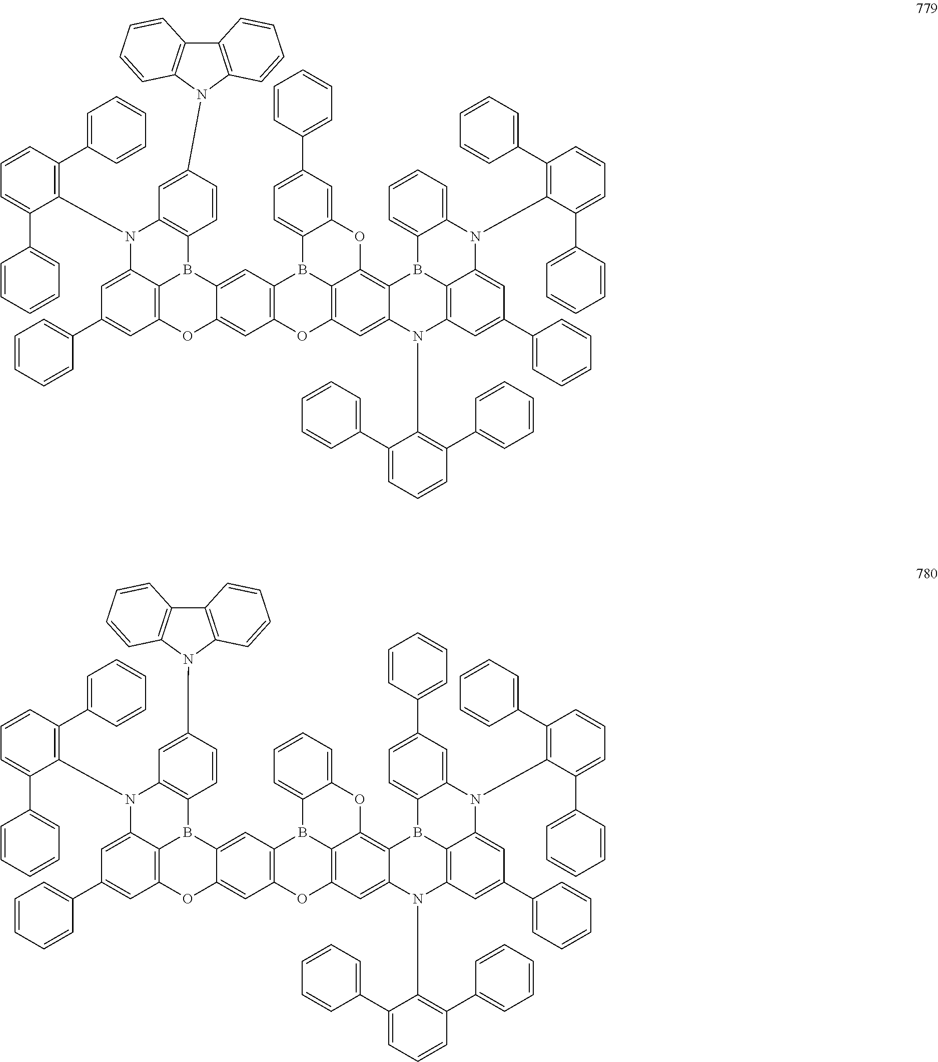 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)O5)cc1 ; c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2O3)Oc2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1] 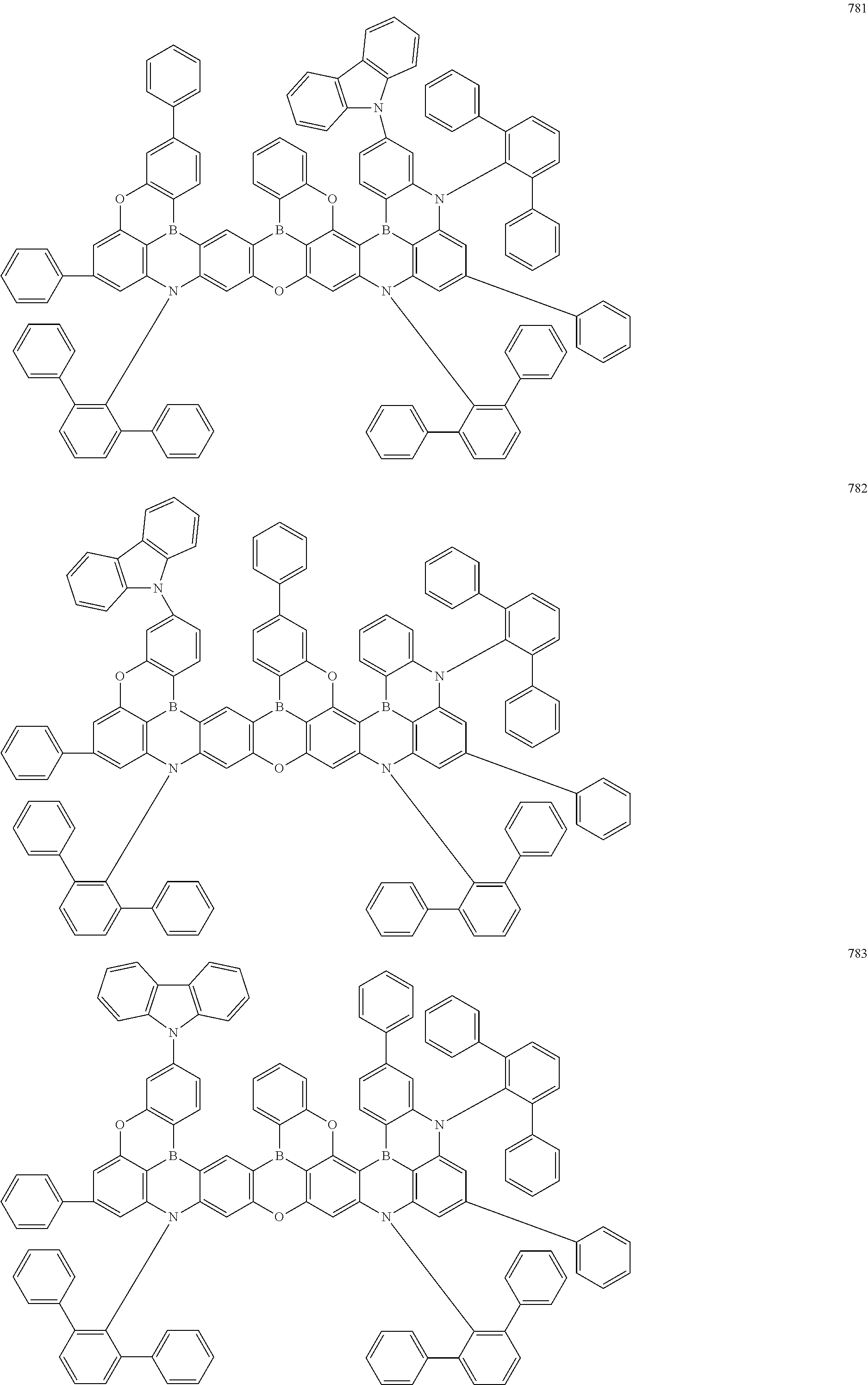 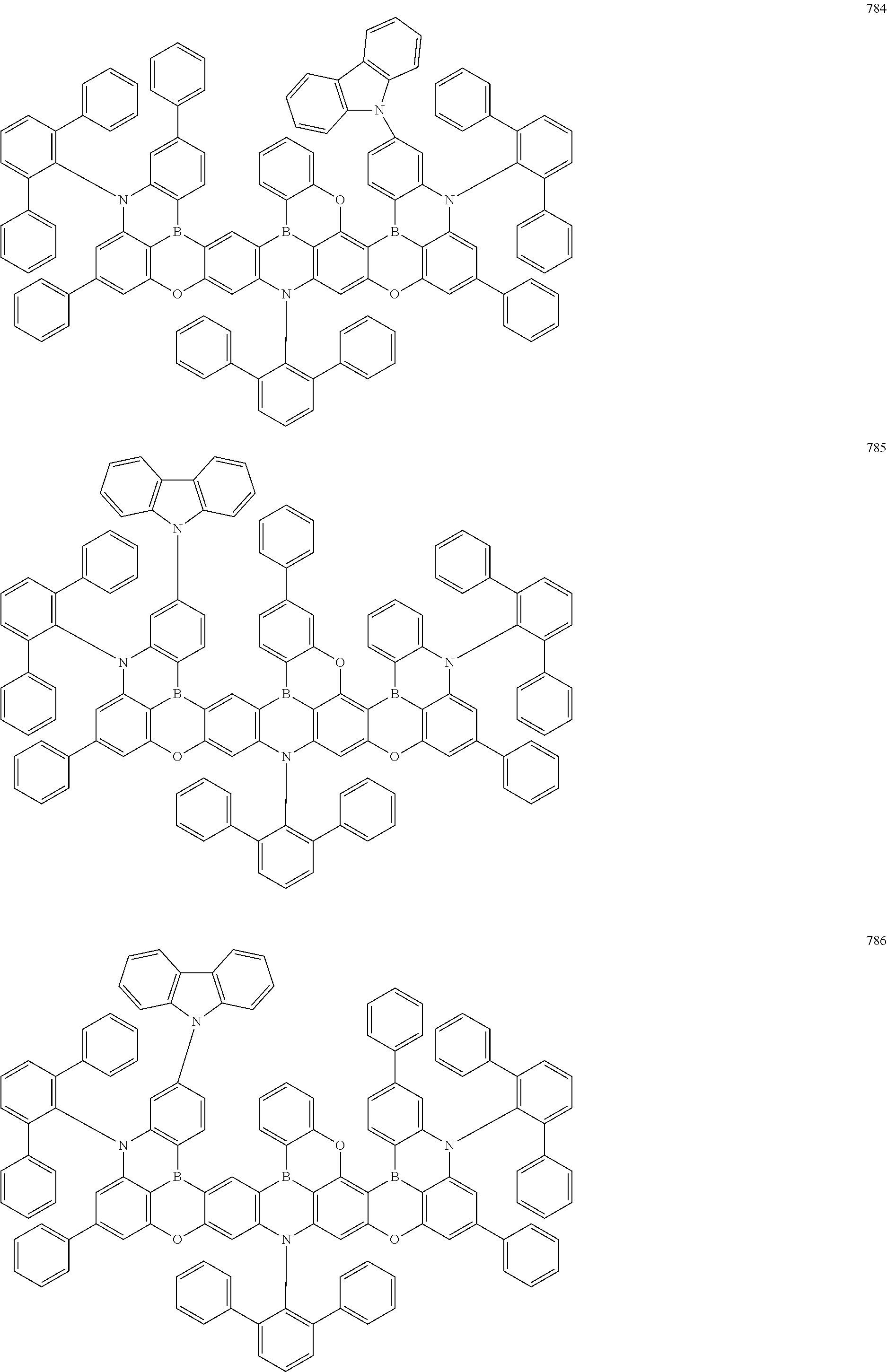 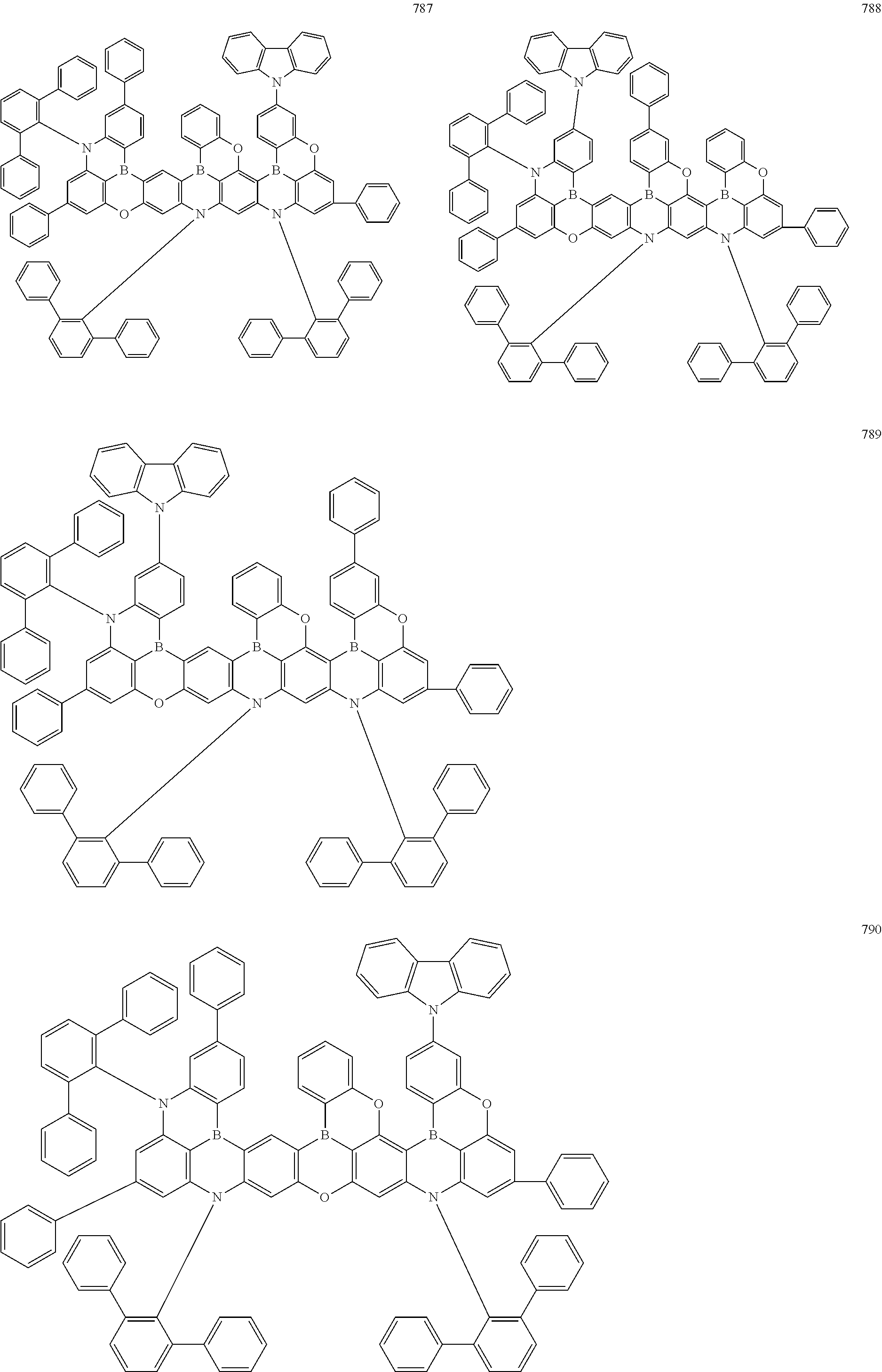 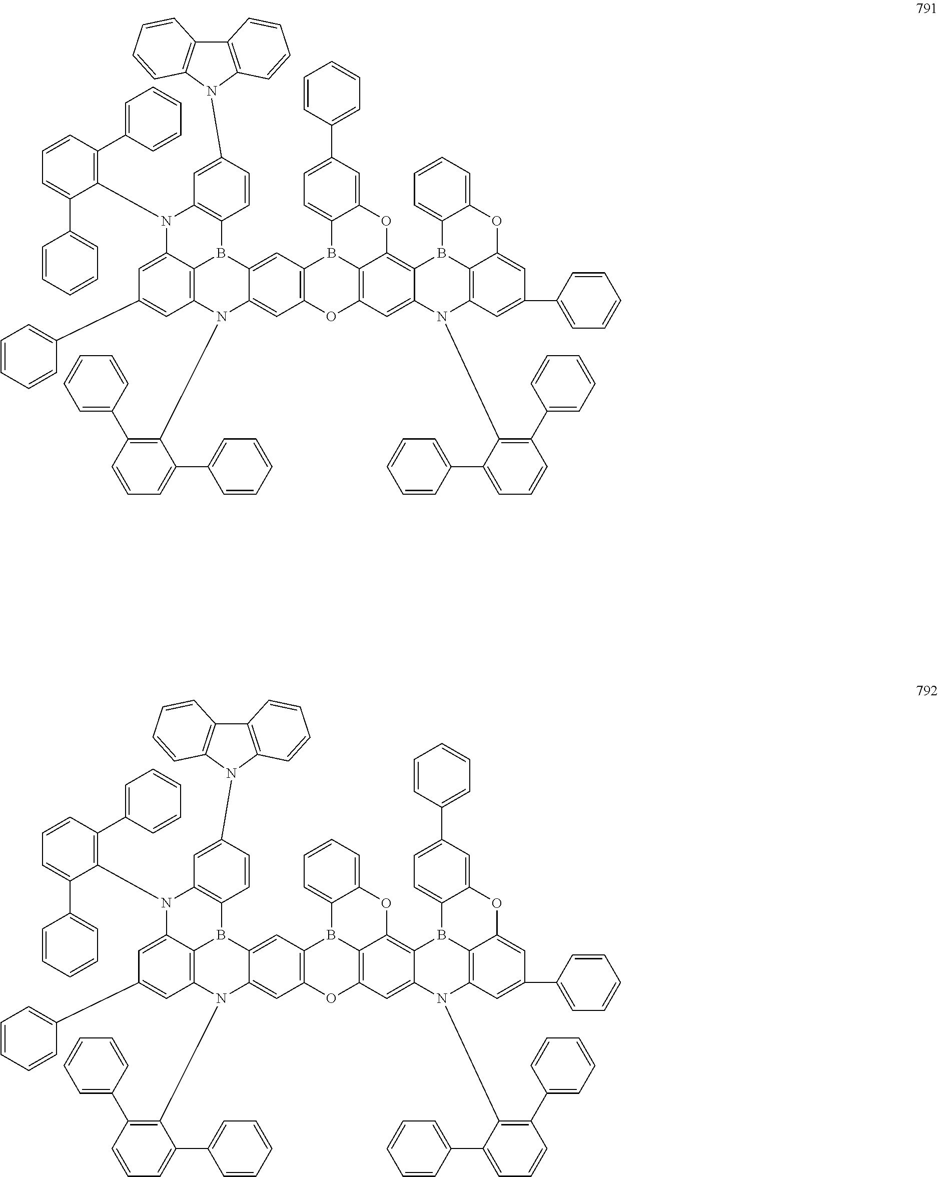 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)N5c2c(-c3ccccc3)cccc2-c2ccccc2)cc1 ; c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1] 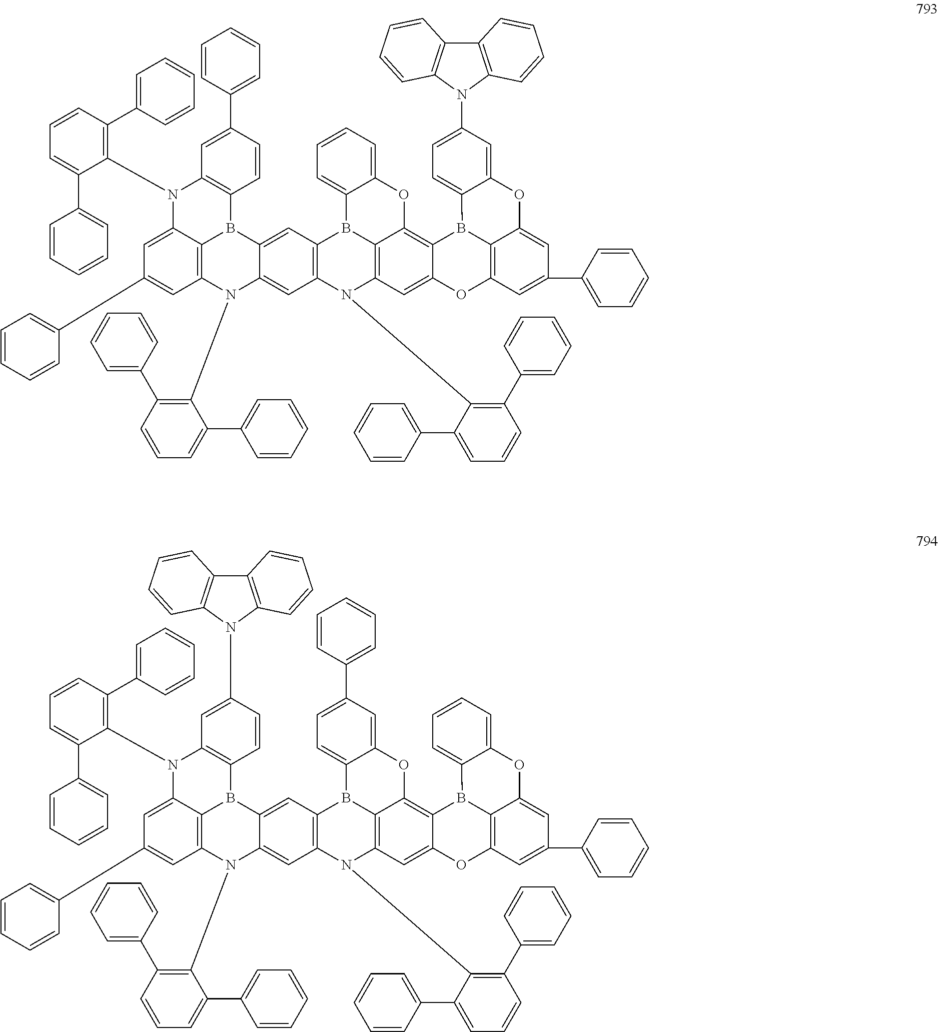 [SMILES: c1ccc(-c2cc3c4c(c2)Oc2cc5c6c(c2B4c2ccc(-n4c7ccccc7c7ccccc74)cc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccc(-c3ccccc3)cc2N4c2c(-c3ccccc3)cccc2-c2ccccc2)cc1 ; c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccc(-n3c6ccccc6c6ccccc63)cc2N5c2c(-c3ccccc3)cccc2-c2ccccc2)Oc2cc(-c3ccccc3)cc3c2B4c2ccccc2O3)cc1] 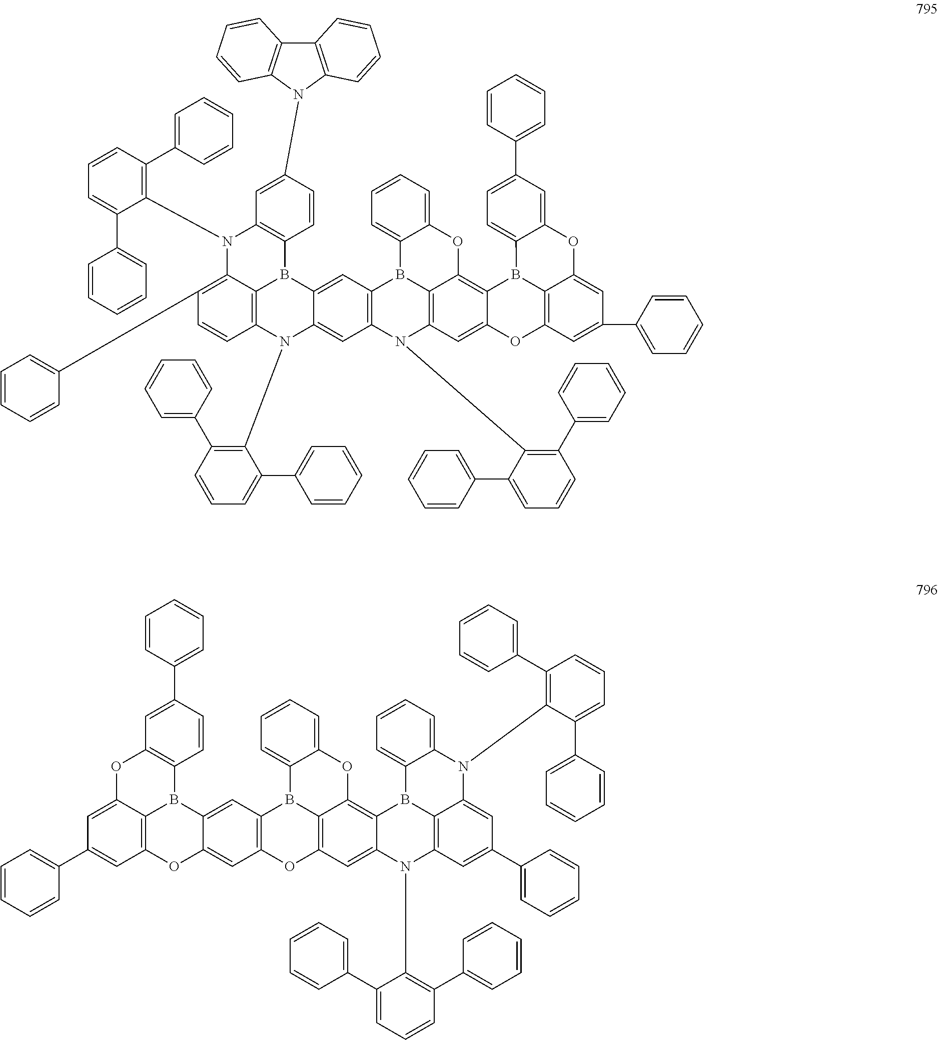 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2ccc(-c3ccccc3)c3c2B5c2ccc(-n5c6ccccc6c6ccccc65)cc2N3c2c(-c3ccccc3)cccc2-c2ccccc2)O4)cc1 ; c1ccc(-c2ccc3c(c2)Oc2cc(-c4ccccc4)cc4c2B3c2cc3c(cc2O4)Oc2cc4c(c5c2B3c2ccccc2O5)B2c3ccccc3N(c3c(-c5ccccc5)cccc3-c3ccccc3)c3cc(-c5ccccc5)cc(c32)N4c2c(-c3ccccc3)cccc2-c2ccccc2)cc1] 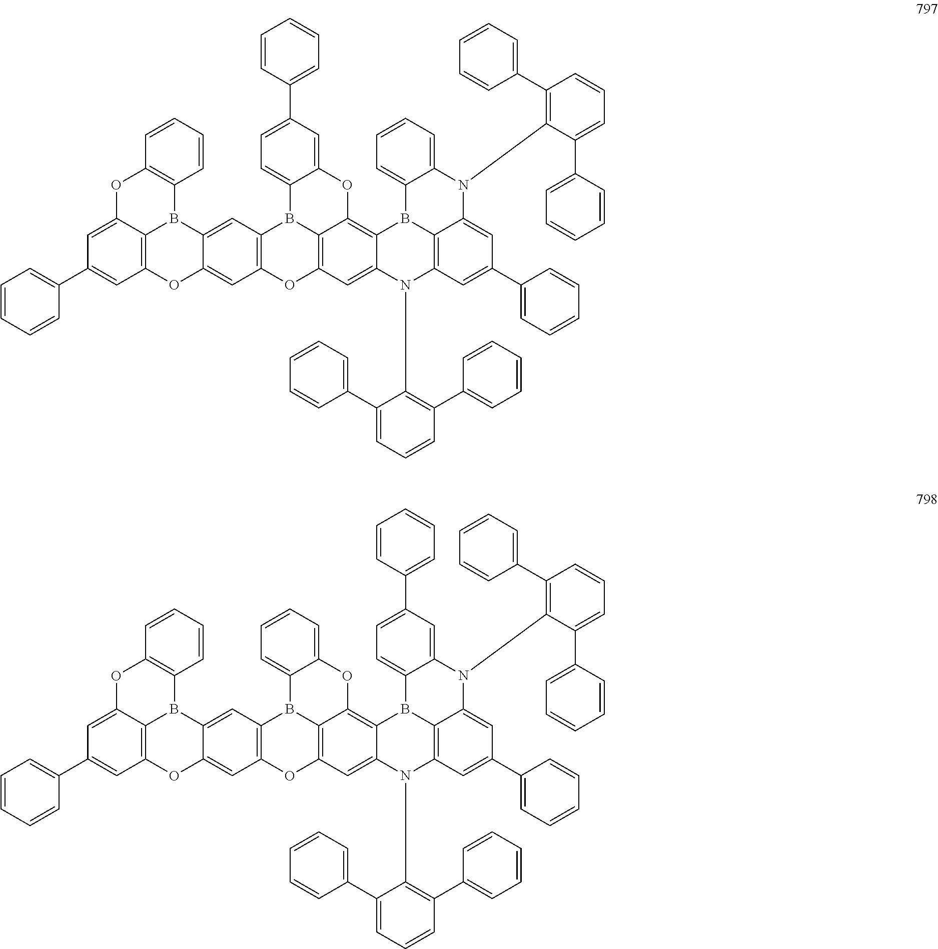 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)Oc2cc5c(cc2B34)B2c3ccccc3Oc3cc(-c4ccccc4)cc(c32)O5)cc1 ; c1ccc(-c2cc3c4c(c2)Oc2cc5c(cc2B4c2ccccc2O3)B2c3ccccc3Oc3c2c(cc2c3B3c4ccc(-c6ccccc6)cc4N(c4c(-c6ccccc6)cccc4-c4ccccc4)c4cc(-c6ccccc6)cc(c43)N2c2c(-c3ccccc3)cccc2-c2ccccc2)O5)cc1] 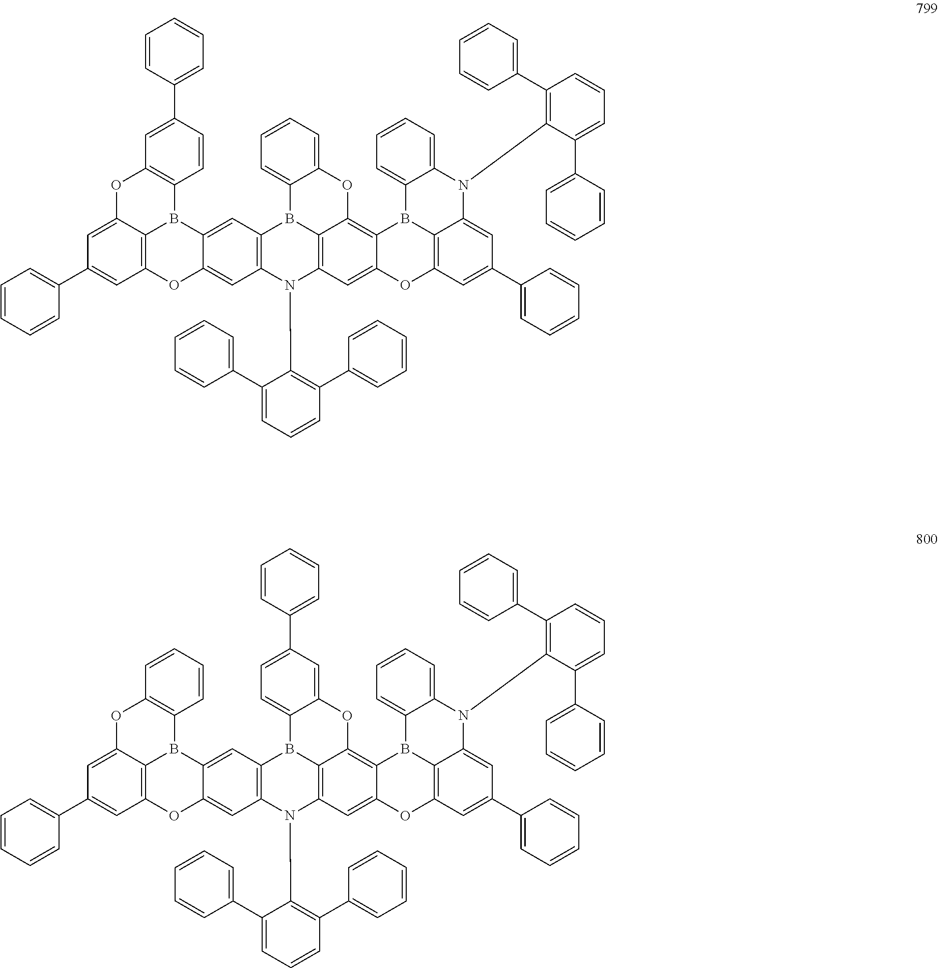 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccccc3N(c3c(-c5ccccc5)cccc3-c3ccccc3)c3cc(-c5ccccc5)cc(c32)O4)cc1 ; c1ccc(-c2ccc3c(c2)Oc2c4c(cc5c2B3c2cc3c(cc2N5c2c(-c5ccccc5)cccc2-c2ccccc2)Oc2cc(-c5ccccc5)cc5c2B3c2ccccc2O5)Oc2cc(-c3ccccc3)cc3c2B4c2ccccc2N3c2c(-c3ccccc3)cccc2-c2ccccc2)cc1] 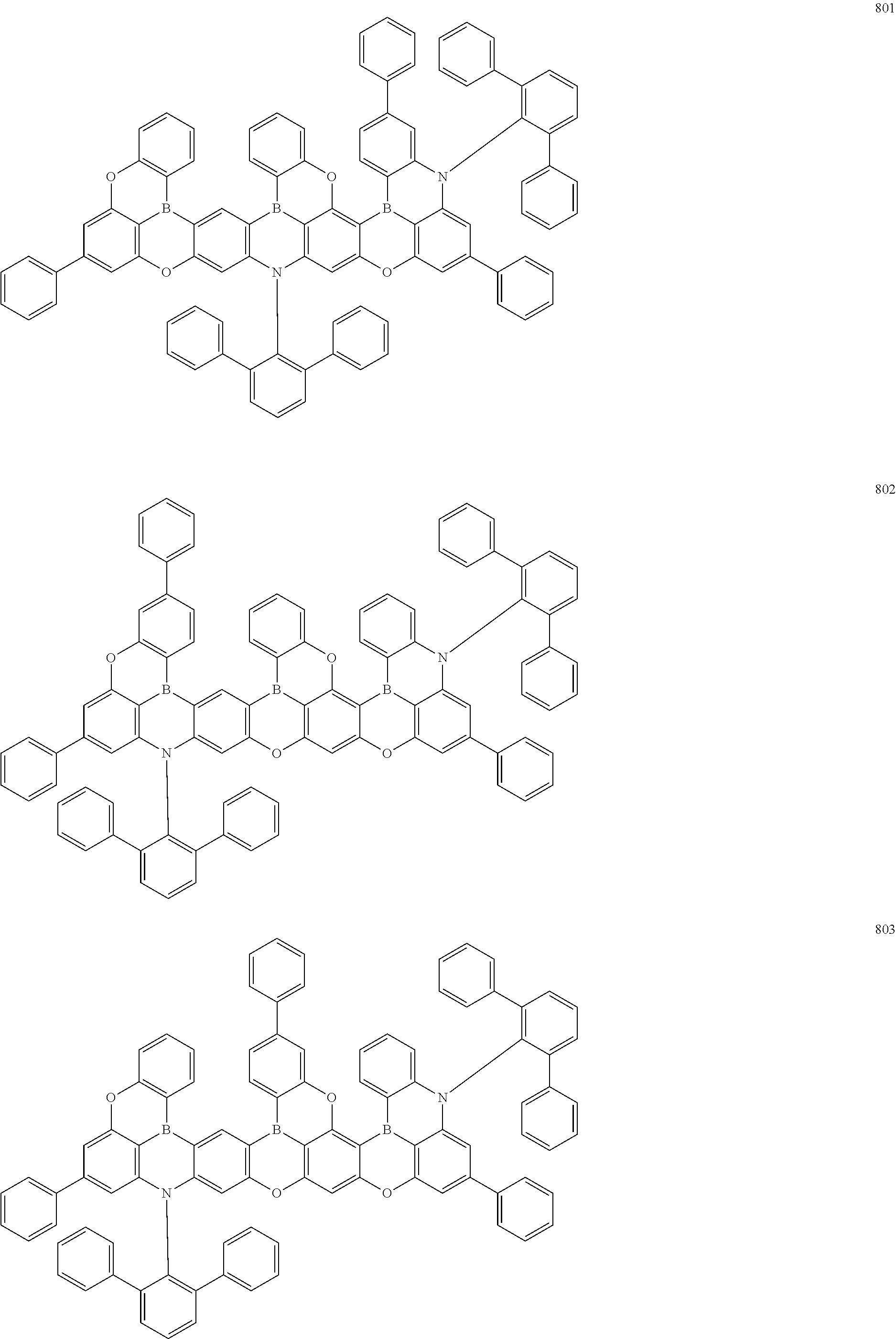 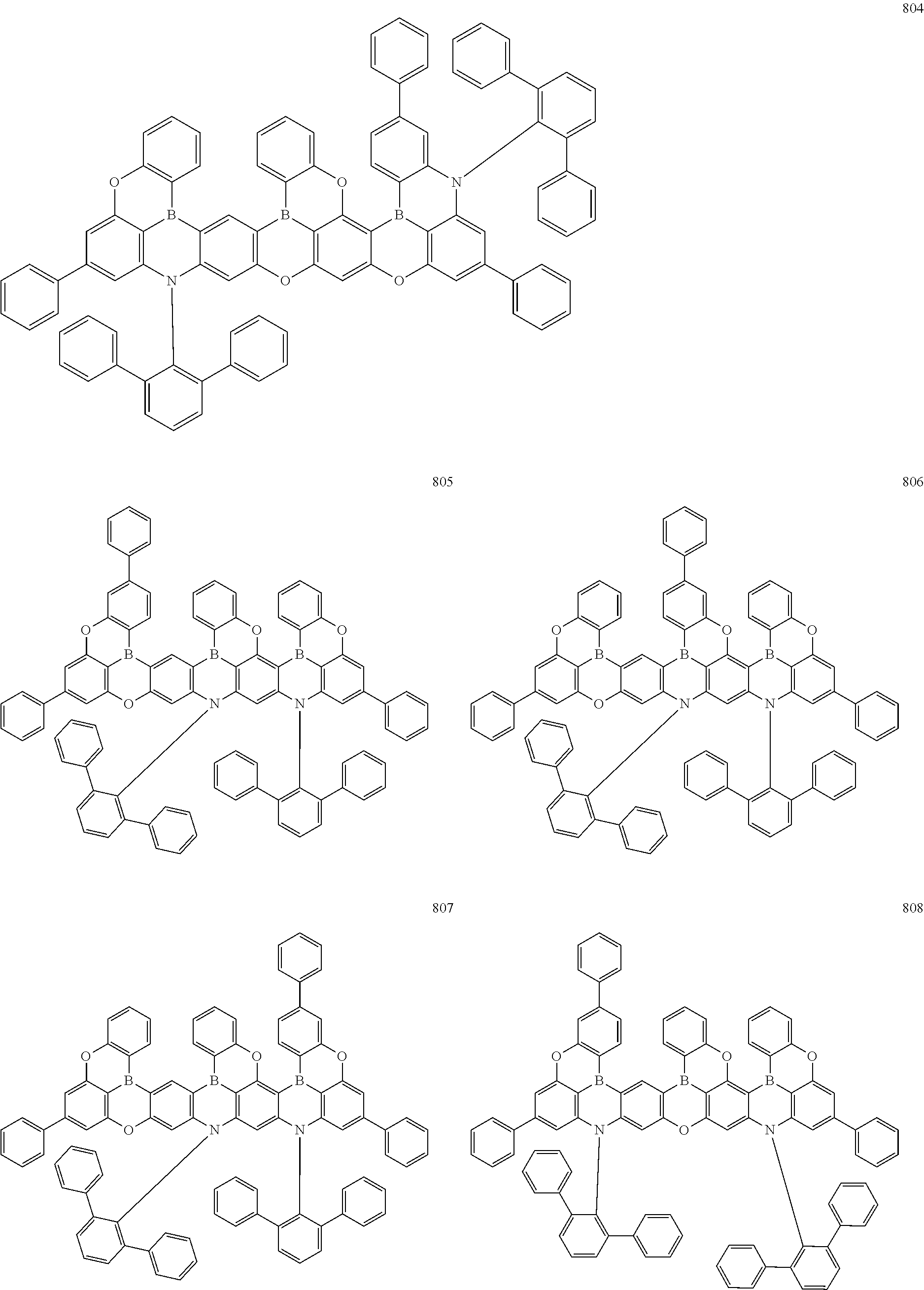 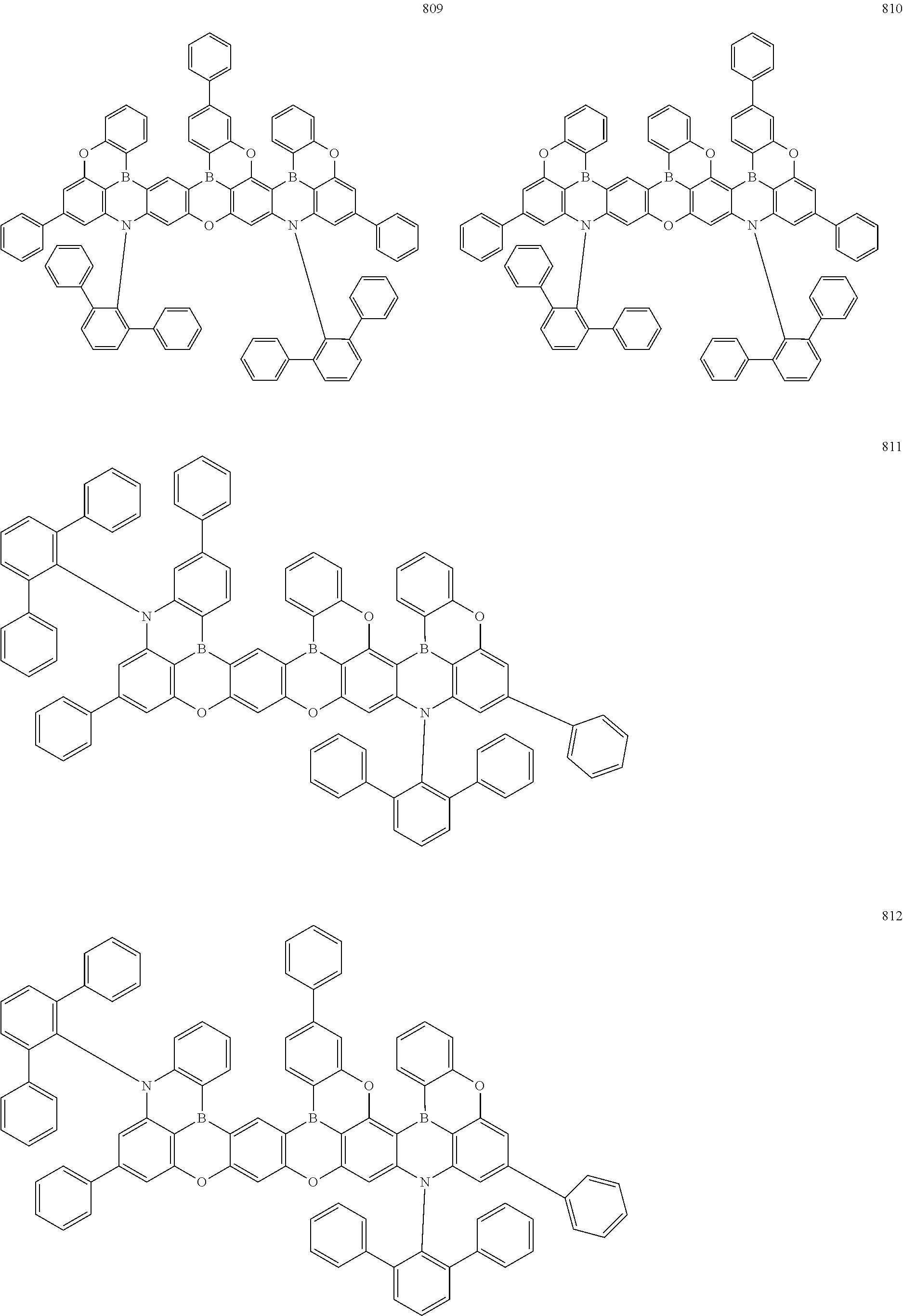 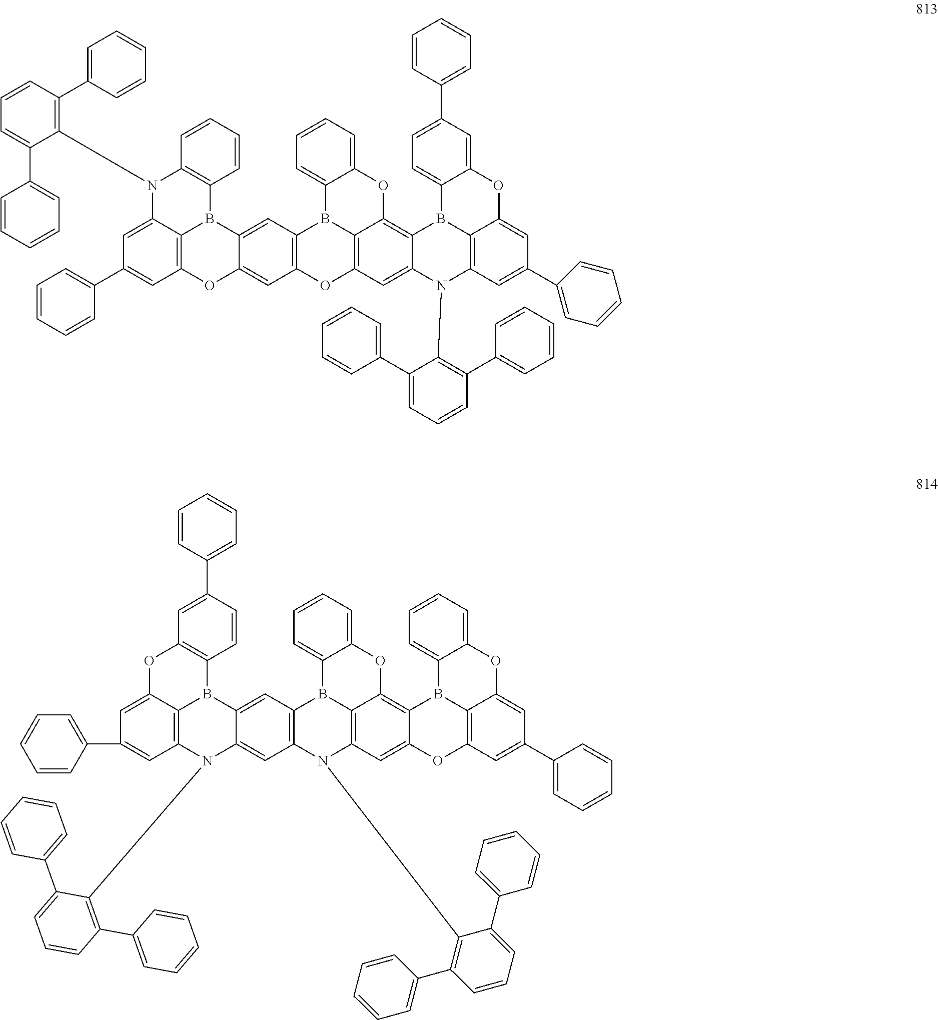 [SMILES: c1ccc(-c2ccc3c(c2)Oc2cc(-c4ccccc4)cc4c2B3c2c(cc3c5c2Oc2ccccc2B5c2cc5c(cc2O3)Oc2cc(-c3ccccc3)cc3c2B5c2ccccc2N3c2c(-c3ccccc3)cccc2-c2ccccc2)N4c2c(-c3ccccc3)cccc2-c2ccccc2)cc1 ; c1ccc(-c2ccc3c(c2)Oc2cc(-c4ccccc4)cc4c2B3c2cc3c(cc2N4c2c(-c4ccccc4)cccc2-c2ccccc2)N(c2c(-c4ccccc4)cccc2-c2ccccc2)c2cc4c(c5c2B3c2ccccc2O5)B2c3ccccc3Oc3cc(-c5ccccc5)cc(c32)O4)cc1] 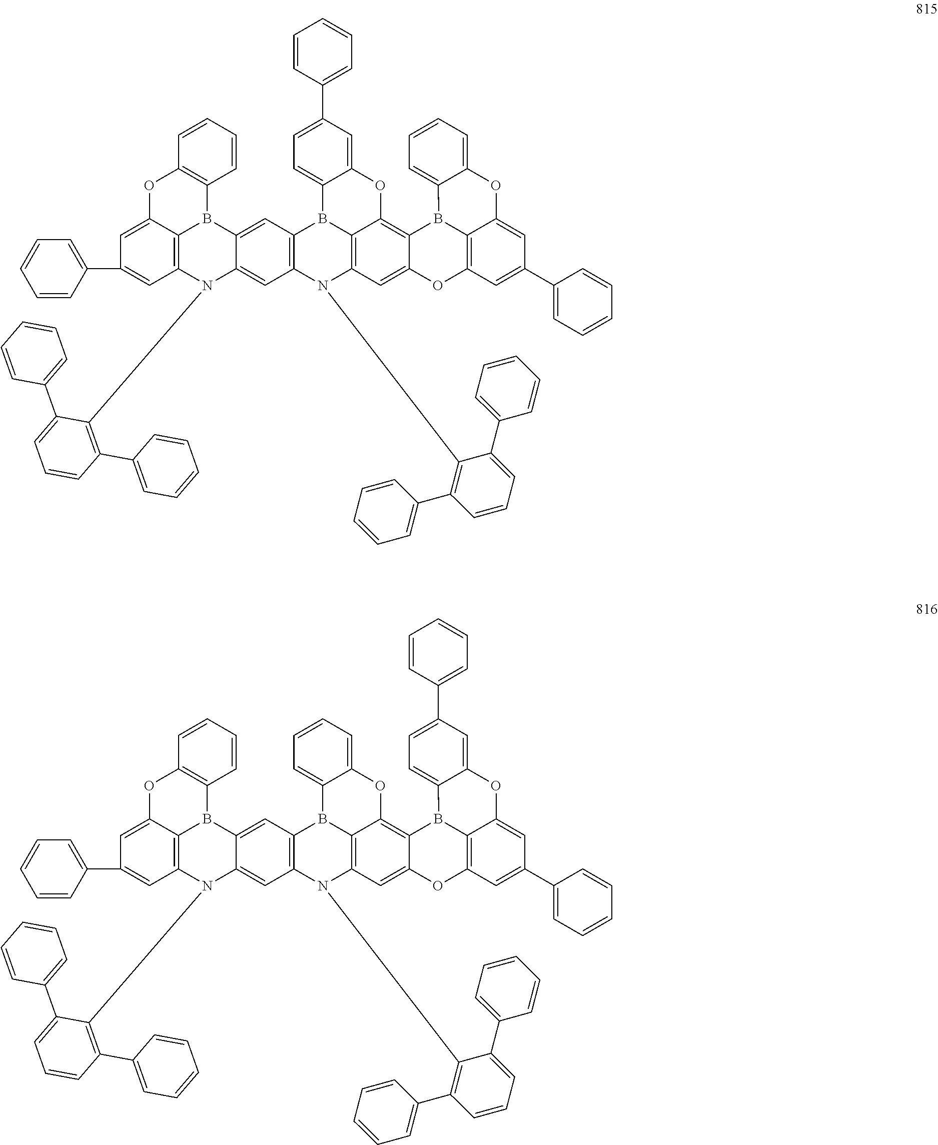 [SMILES: c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccccc2O5)Oc2cc(-c3ccccc3)cc3c2B4c2ccccc2O3)cc1 ; c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2cc(-c3ccccc3)cc3c2B5c2ccccc2O3)O4)cc1] 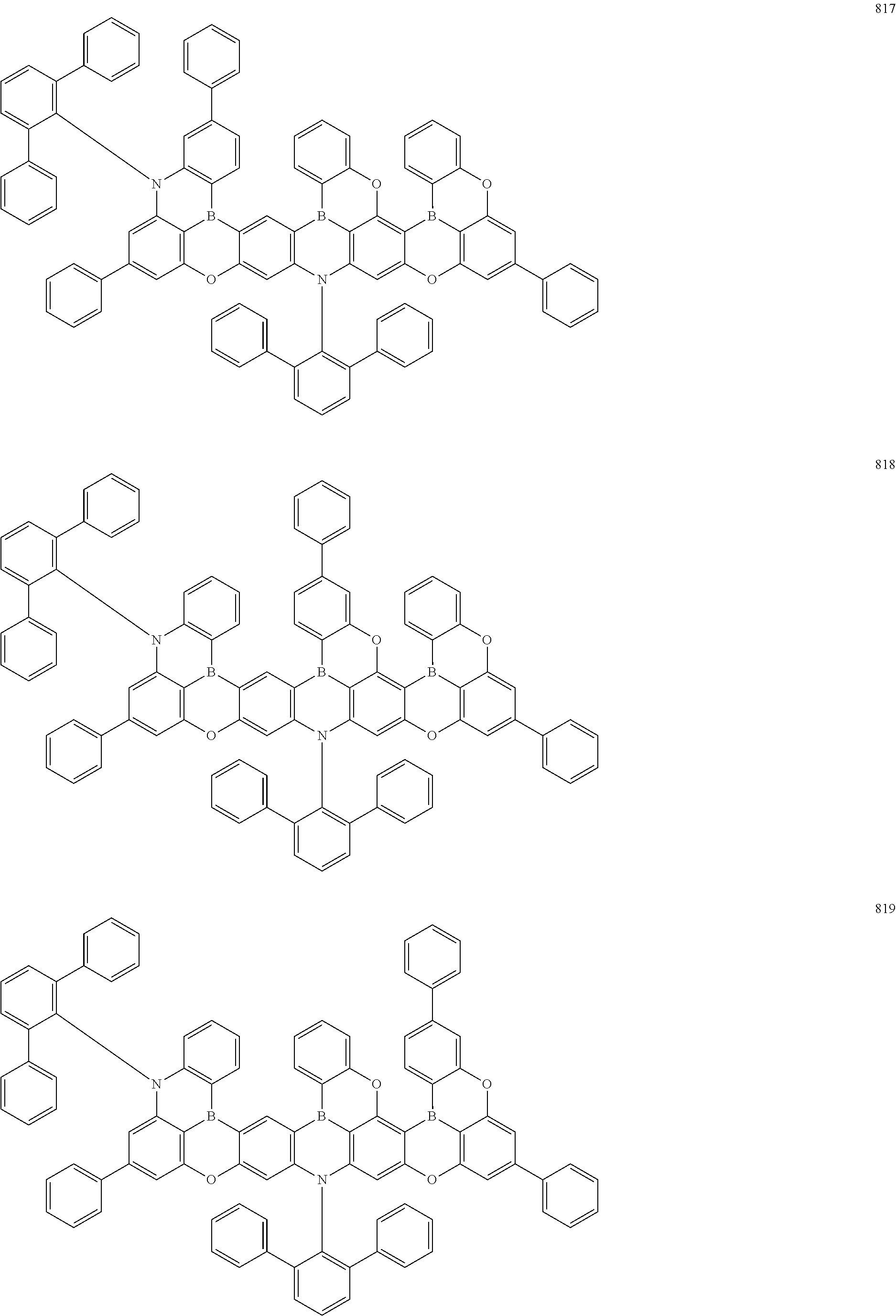 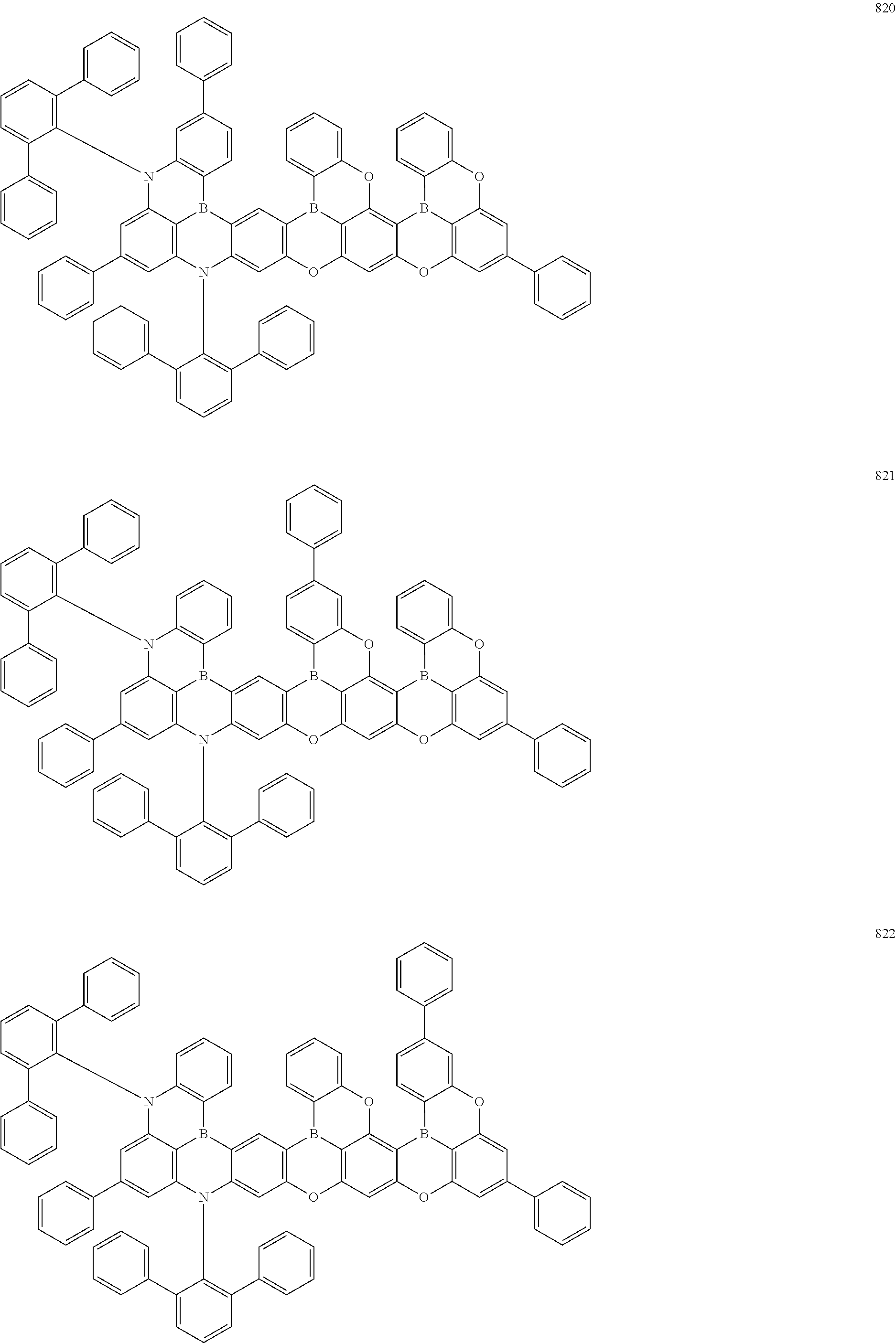 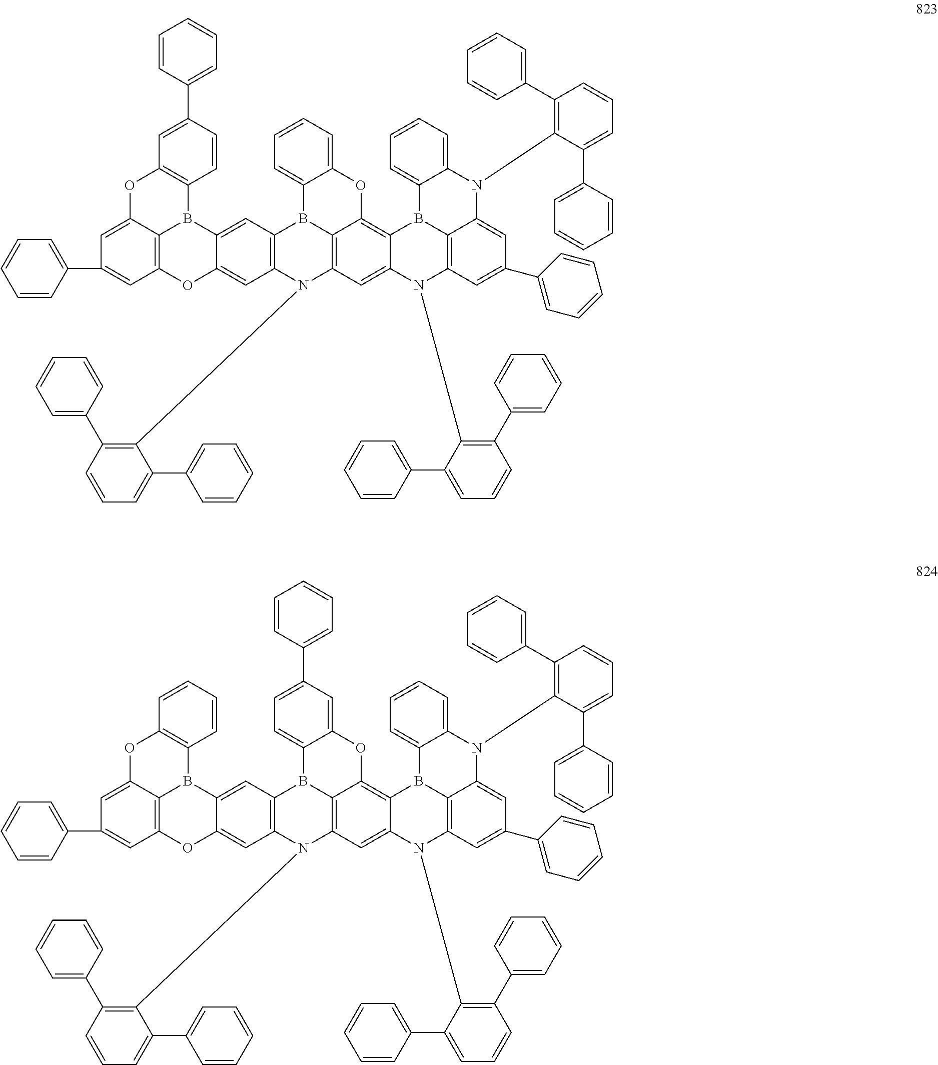 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccccc3N(c3c(-c5ccccc5)cccc3-c3ccccc3)c3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccccc3Oc3cc(-c4ccccc4)cc(c32)O5)cc1] 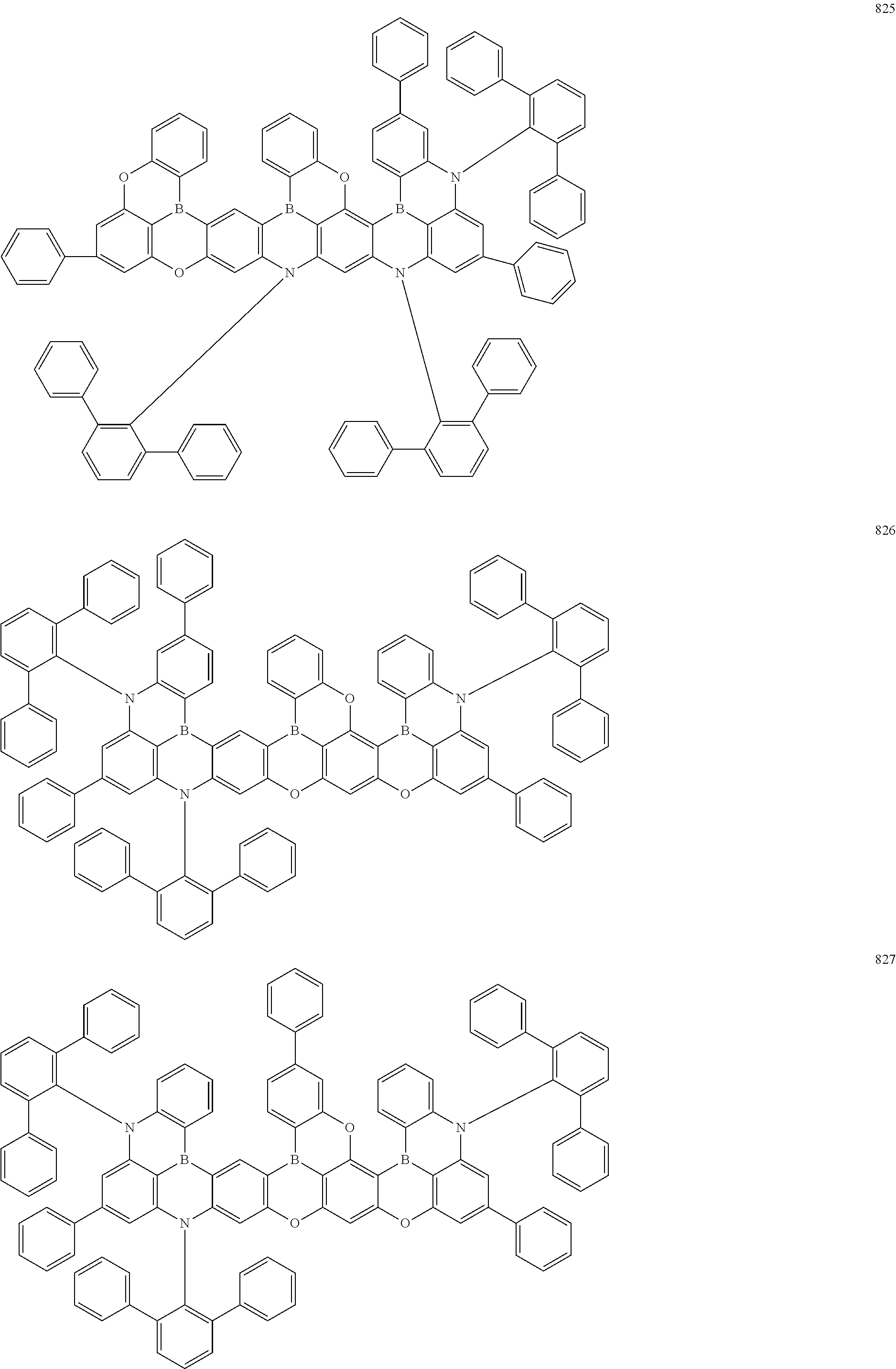 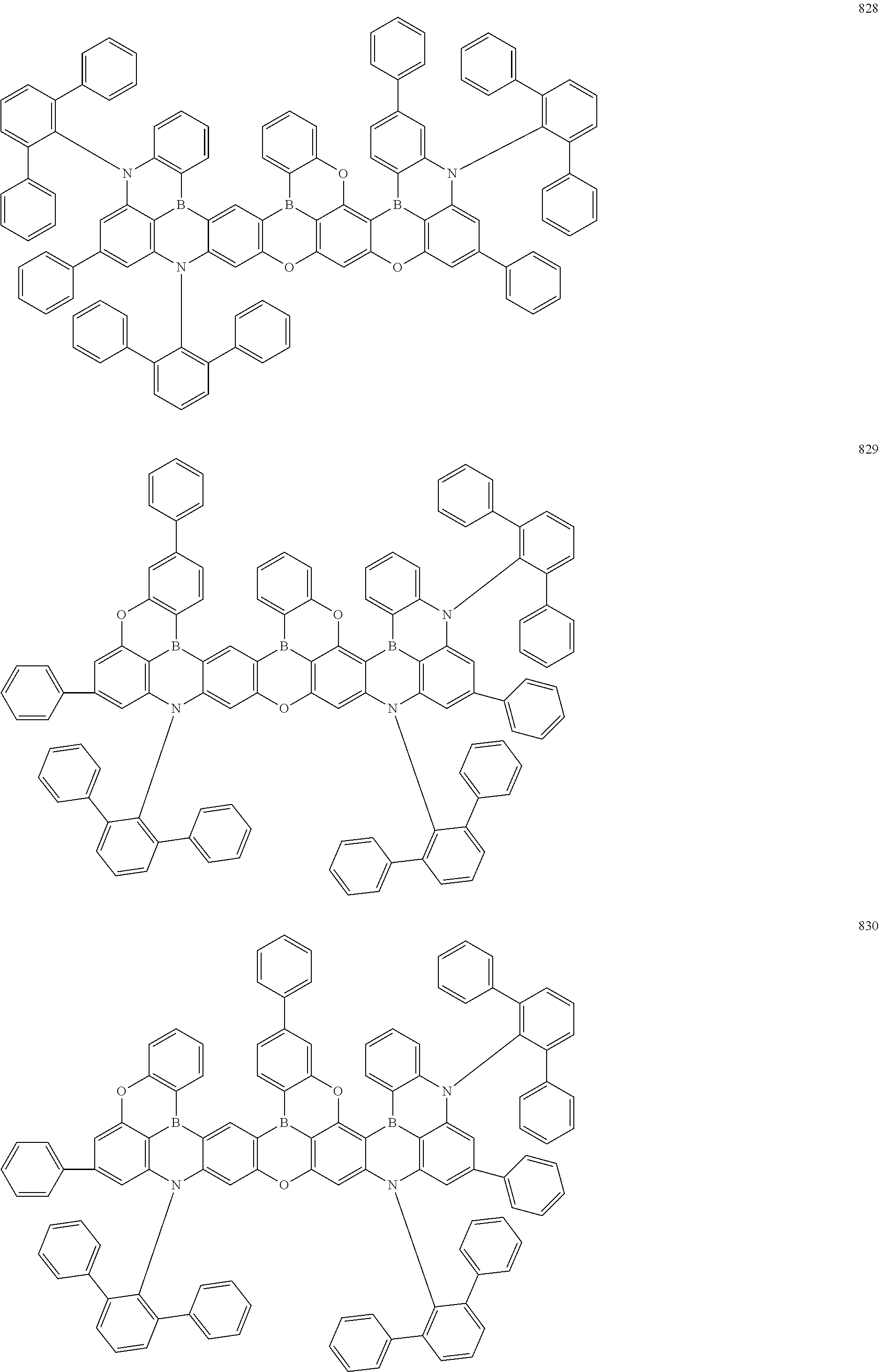 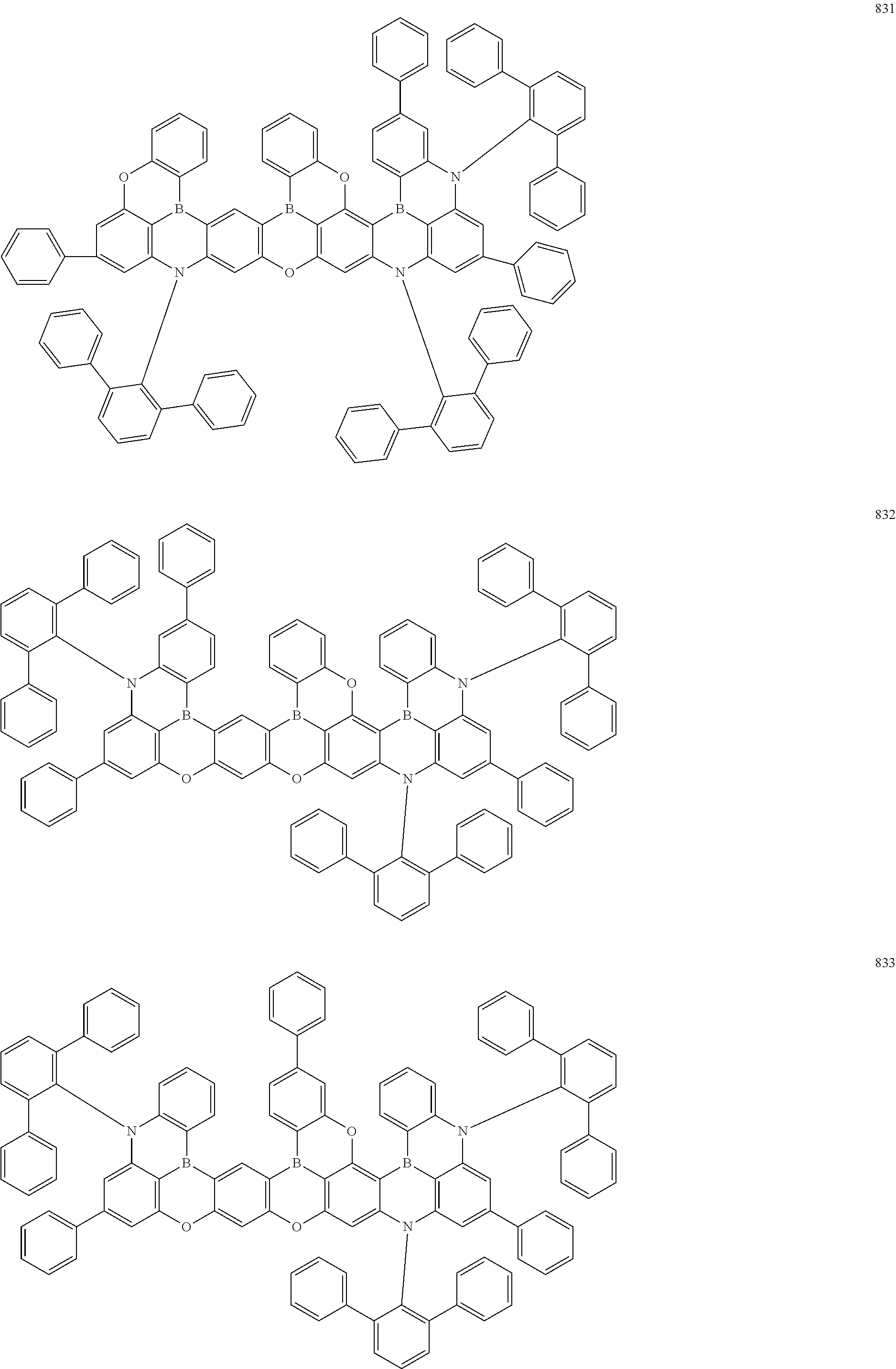 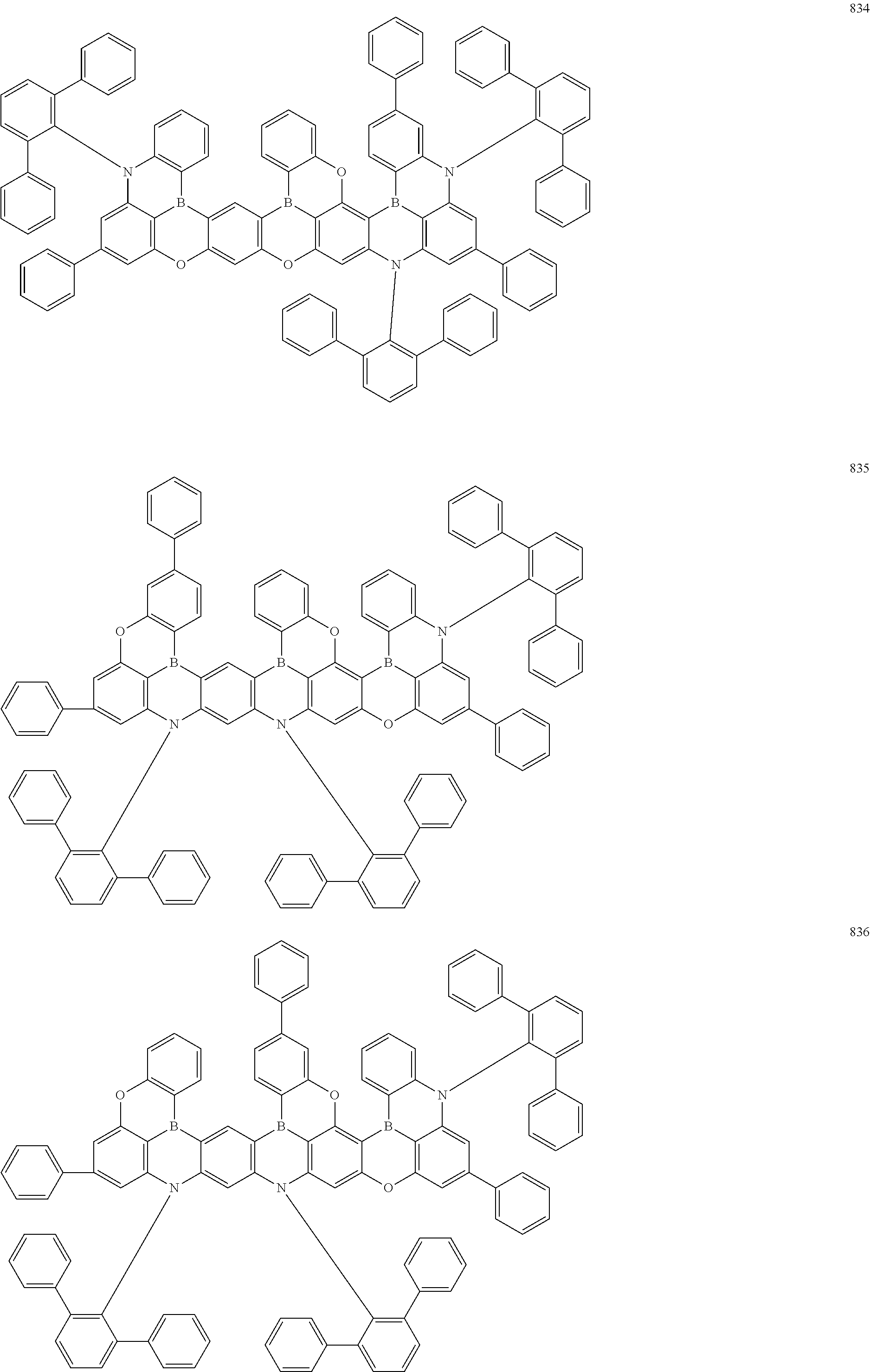 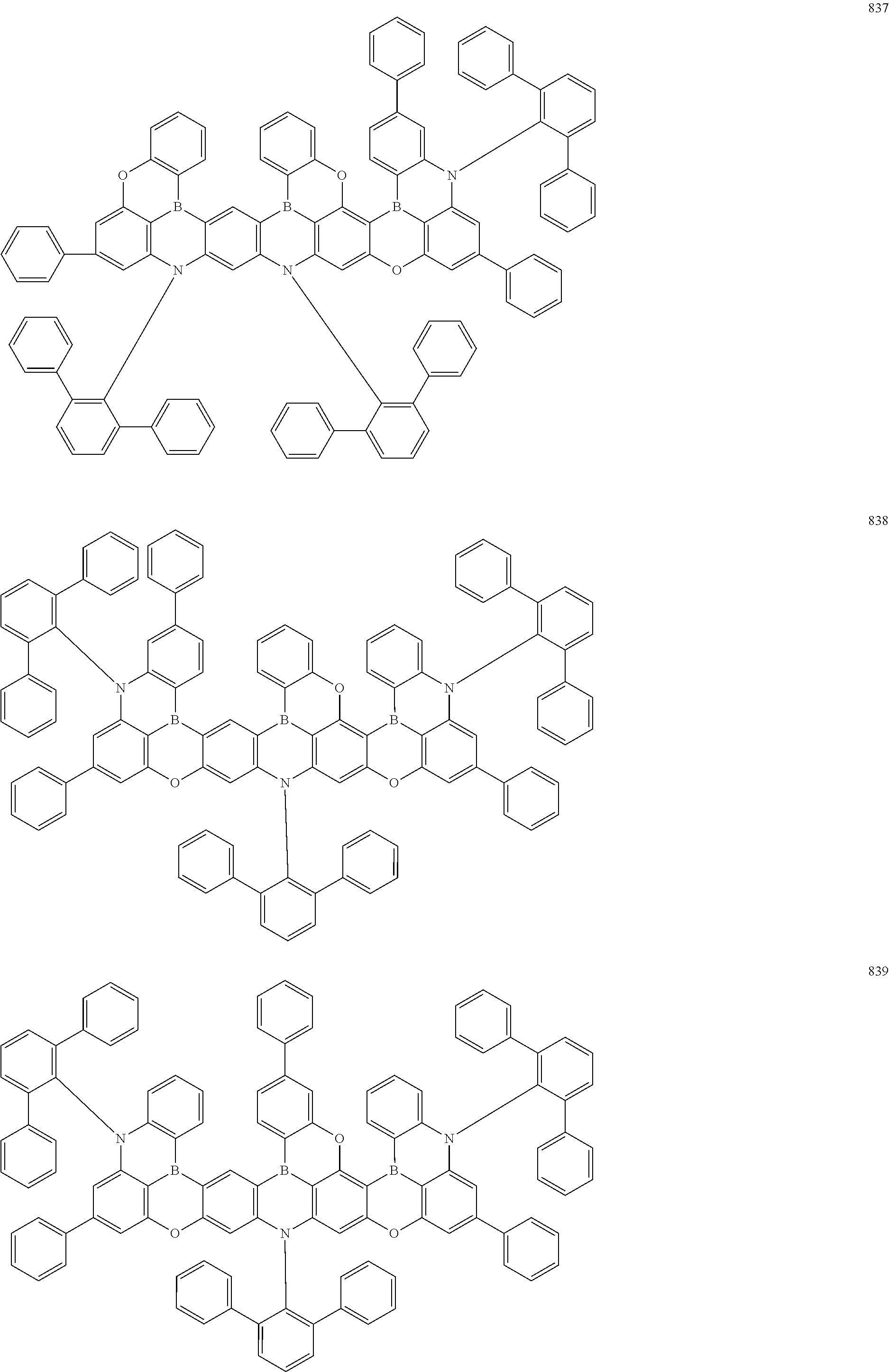 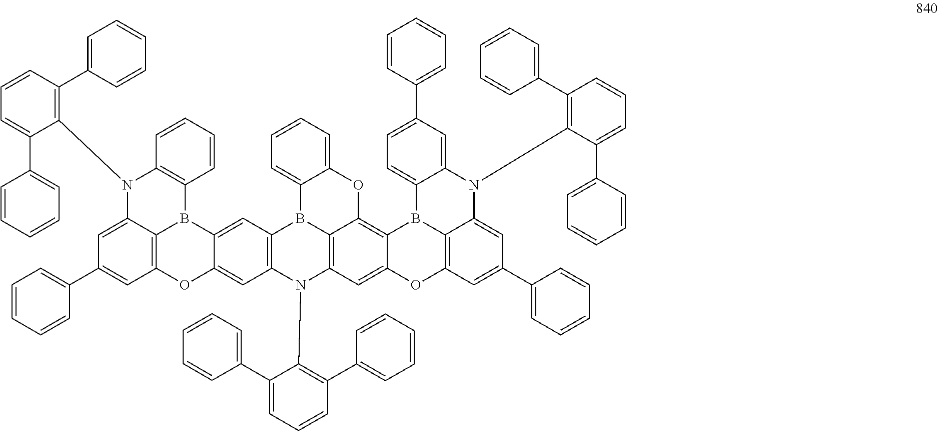 [SMILES: c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccccc2N3c2c(-c3ccccc3)cccc2-c2ccccc2)O4)cc1] 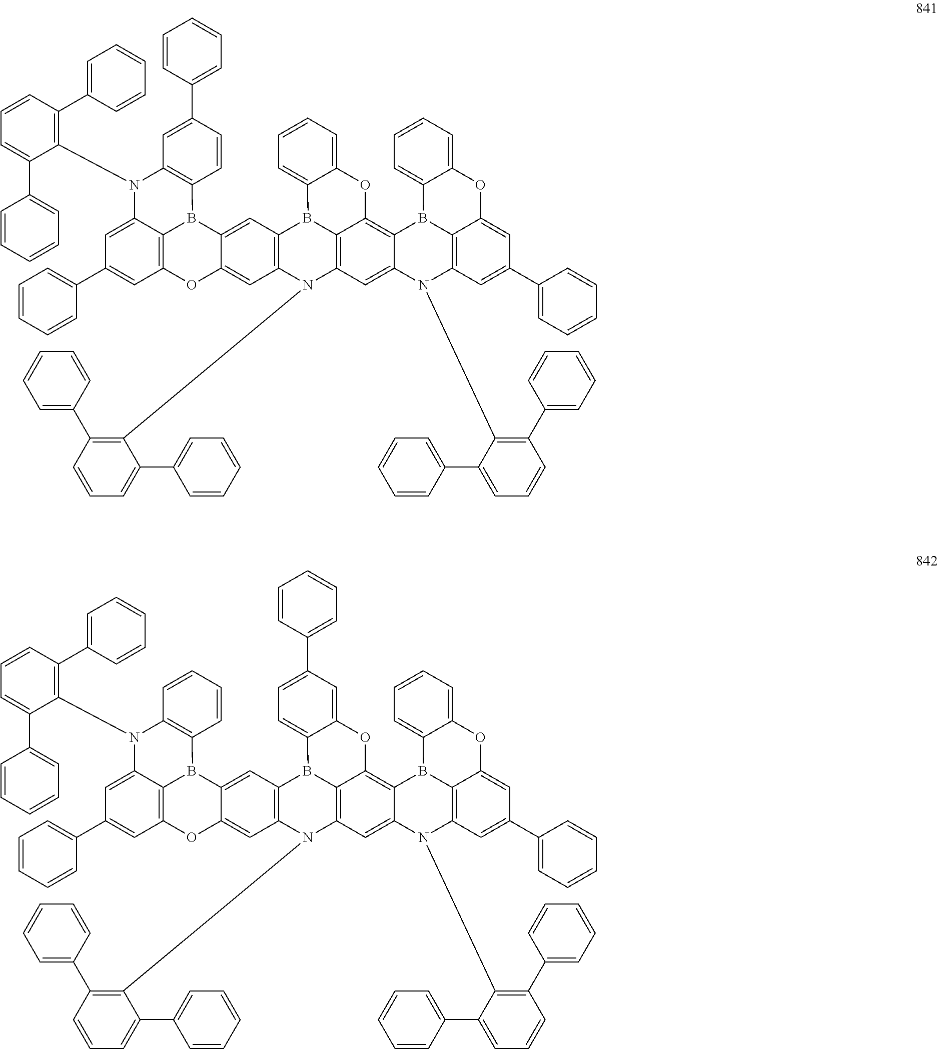 [SMILES: c1ccc(-c2ccc3c(c2)N(c2c(-c4ccccc4)cccc2-c2ccccc2)c2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccccc3Oc3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccccc3N(c3c(-c4ccccc4)cccc3-c3ccccc3)c3cc(-c4ccccc4)cc(c32)O5)cc1] 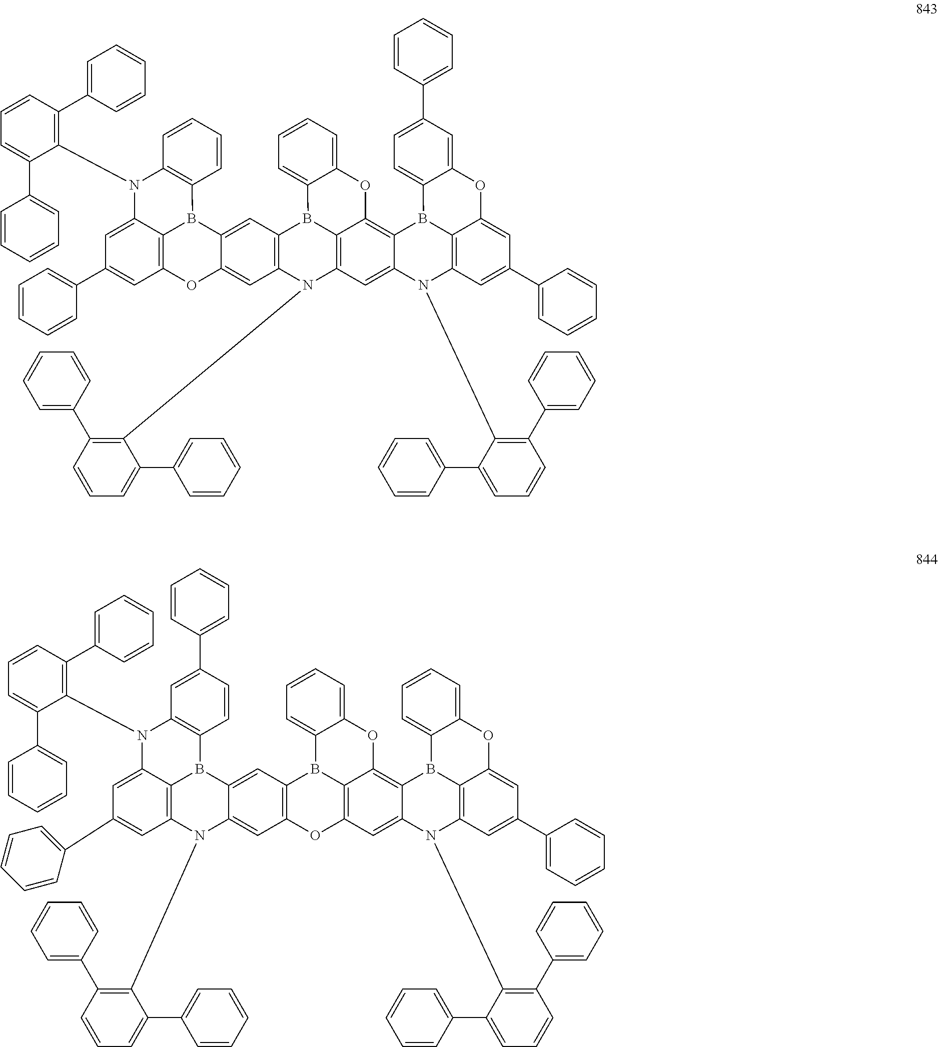 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccccc2N3c2c(-c3ccccc3)cccc2-c2ccccc2)N4c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2cc3c(cc2N4c2c(-c4ccccc4)cccc2-c2ccccc2)Oc2cc4c(c5c2B3c2ccccc2O5)B2c3ccccc3Oc3cc(-c5ccccc5)cc(c32)N4c2c(-c3ccccc3)cccc2-c2ccccc2)cc1] 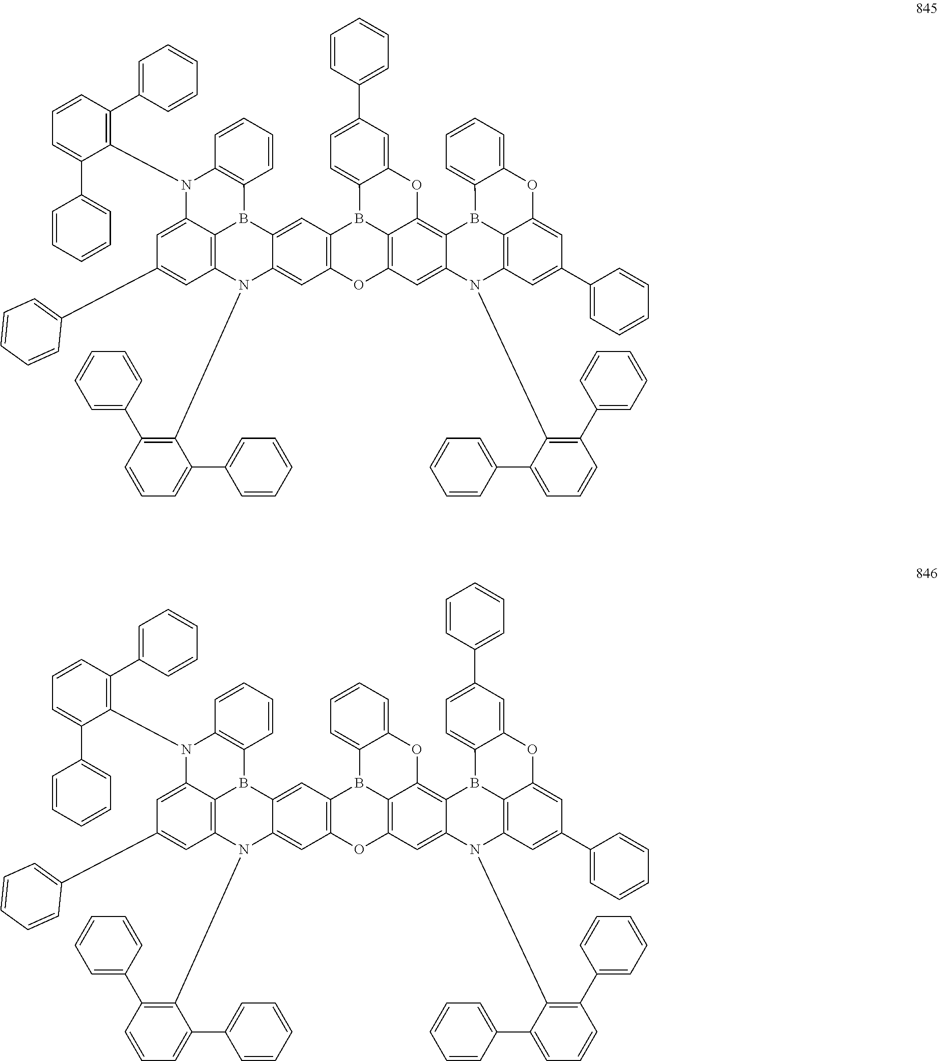 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccccc3N(c3c(-c4ccccc4)cccc3-c3ccccc3)c3cc(-c4ccccc4)cc(c32)N5c2c(-c3ccccc3)cccc2-c2ccccc2)cc1 ; c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccccc2N3c2c(-c3ccccc3)cccc2-c2ccccc2)N4c2c(-c3ccccc3)cccc2-c2ccccc2)cc1] 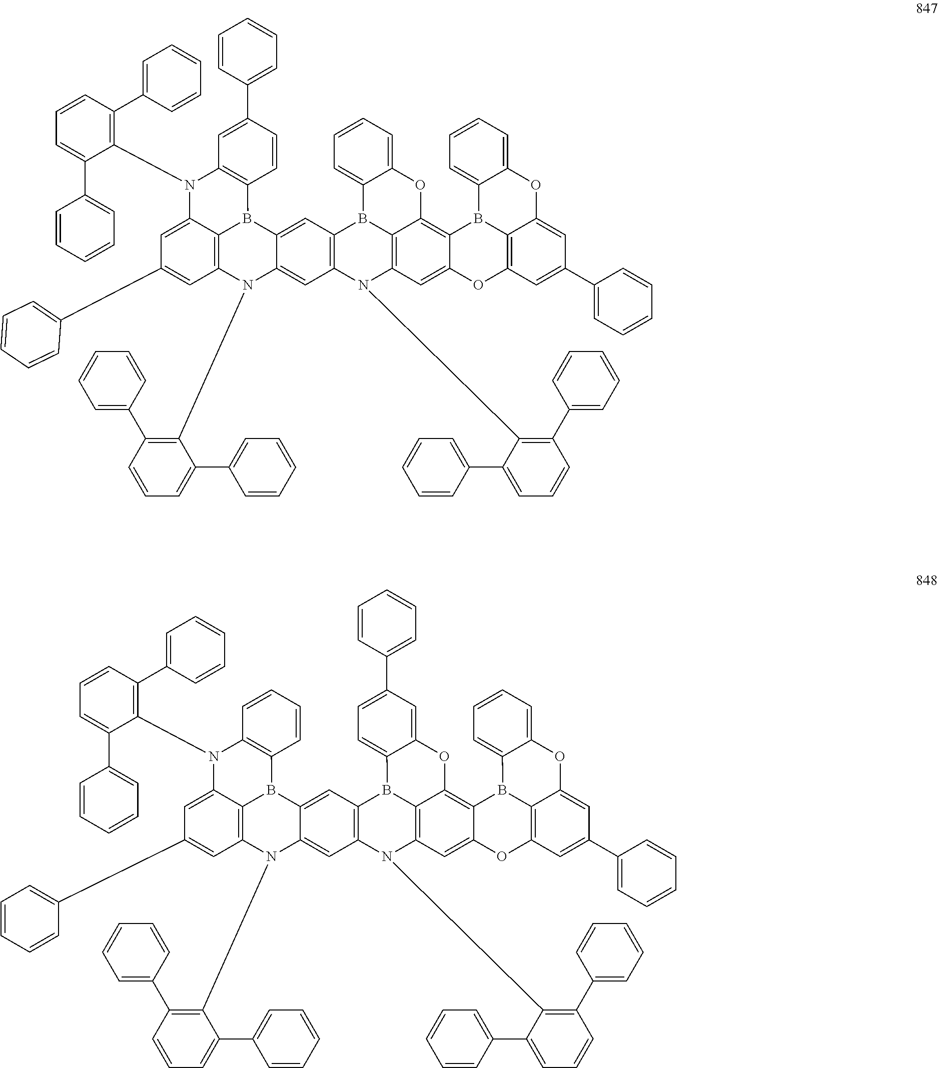 [SMILES: c1ccc(-c2cc3c4c(c2)Oc2cc5c6c(c2B4c2ccccc2O3)Oc2ccccc2B6c2cc3c(cc2N5c2c(-c4ccccc4)cccc2-c2ccccc2)N(c2c(-c4ccccc4)cccc2-c2ccccc2)c2cc(-c4ccccc4)cc4c2B3c2ccc(-c3ccccc3)cc2N4c2c(-c3ccccc3)cccc2-c2ccccc2)cc1 ; c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccccc2N5c2c(-c3ccccc3)cccc2-c2ccccc2)Oc2cc(-c3ccccc3)cc3c2B4c2ccccc2O3)cc1] 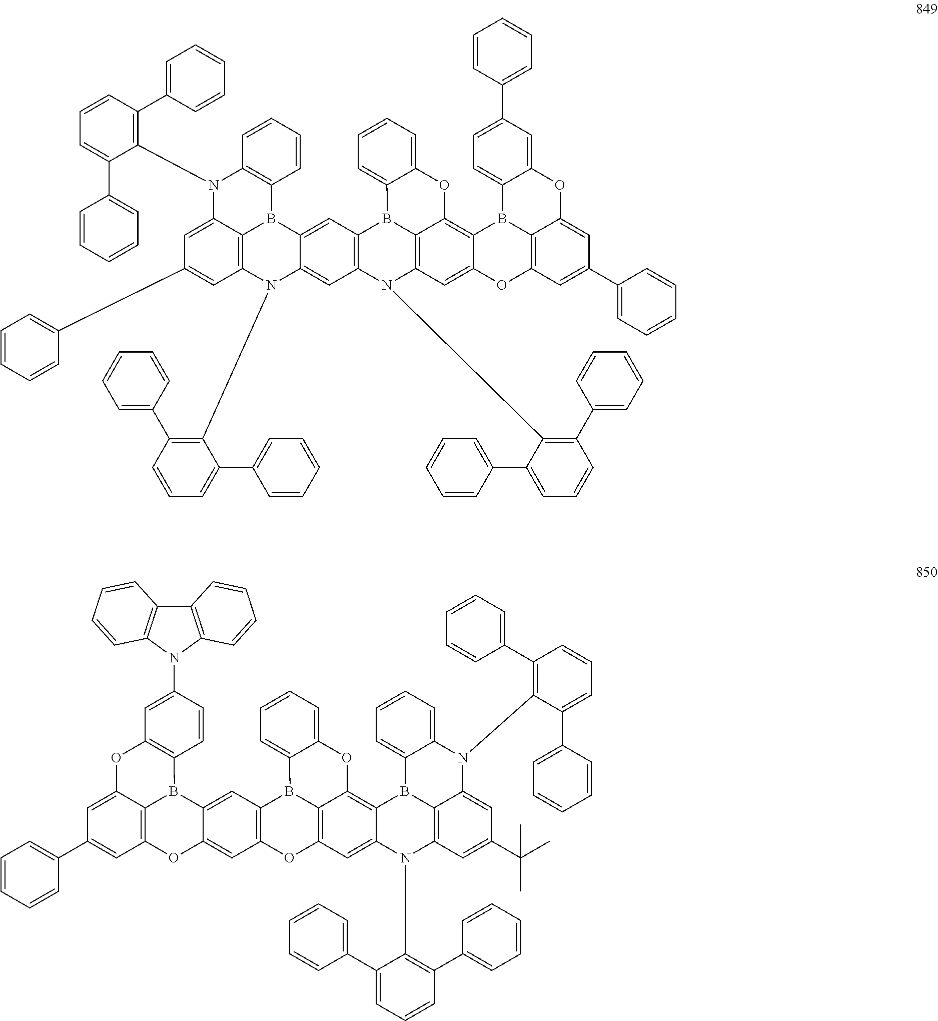 [SMILES: c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2cc(-c3ccccc3)cc3c2B5c2ccccc2N3c2c(-c3ccccc3)cccc2-c2ccccc2)O4)cc1 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1O3] 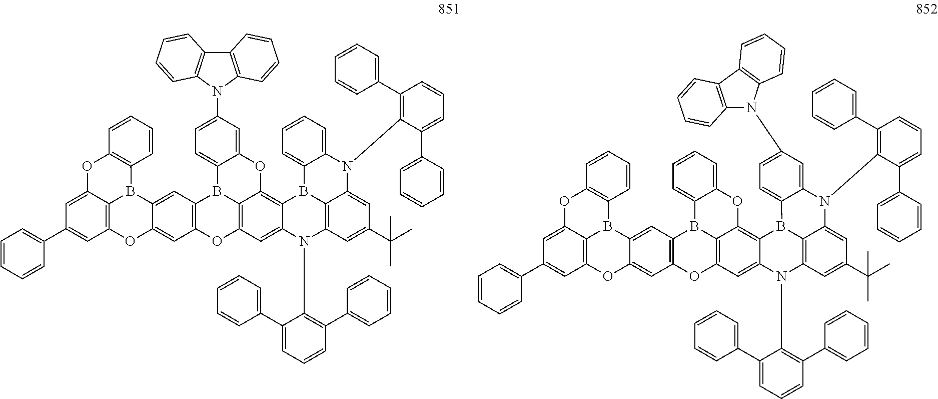 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1O4)Oc1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)Oc1cc(-c3ccccc3)cc3c1B2c1ccccc1O3] 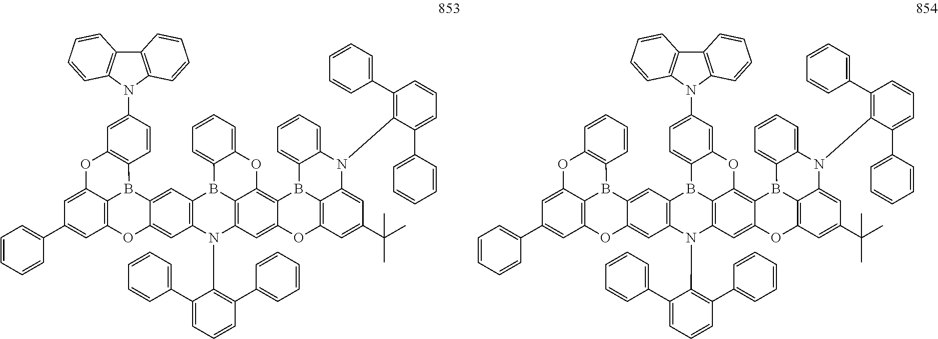 [SMILES: CC(C)(C)c1cc2c3c(c1)N(c1c(-c4ccccc4)cccc1-c1ccccc1)c1ccccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1N3c1c(-c3ccccc3)cccc1-c1ccccc1)Oc1cc(-c3ccccc3)cc3c1B4c1ccccc1O3)O2] 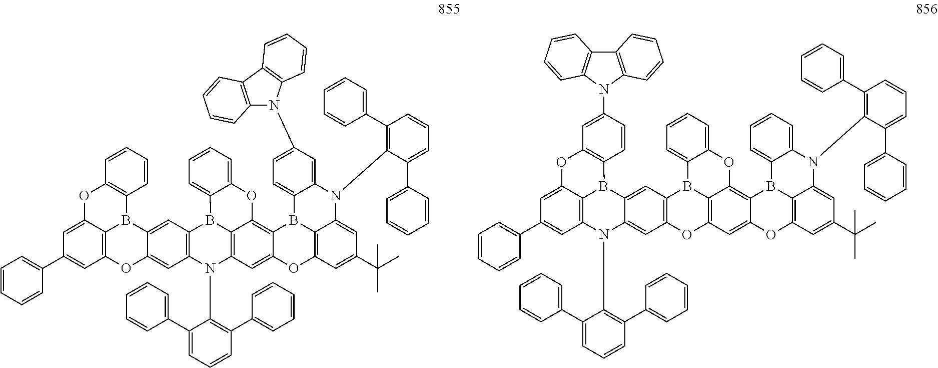 [SMILES: CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccccc1O3)O2 ; CC(C)(C)c1cc2c3c(c1)N(c1c(-c4ccccc4)cccc1-c1ccccc1)c1ccccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1O3)O2] 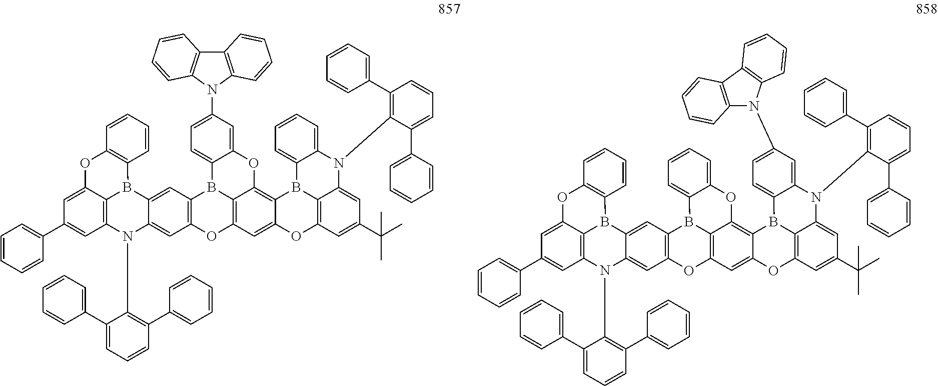 [SMILES: CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1O3)N(c1c(-c3ccccc3)cccc1-c1ccccc1)c1cc(-c3ccccc3)cc3c1B4c1ccccc1O3)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccccc1O3)O2] 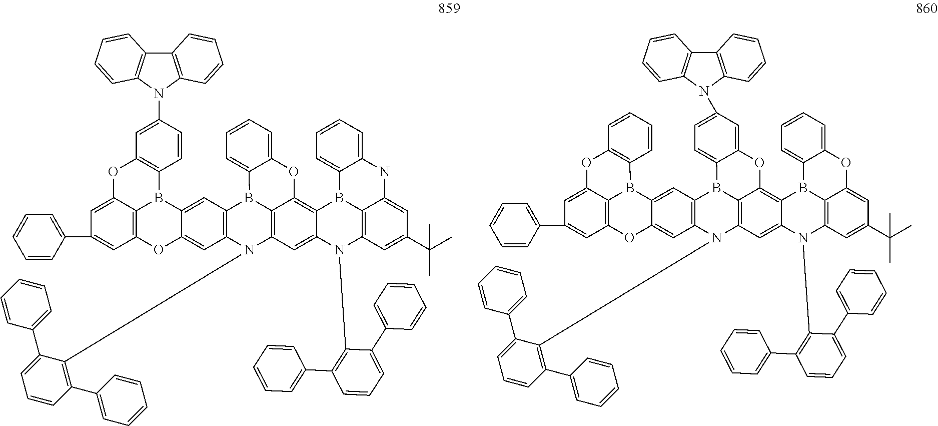 [SMILES: CC(C)(C)c1cc2c3c(c1)N(c1c(-c4ccccc4)cccc1-c1ccccc1)c1cc4c5c(c1B3c1ccccc1N2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1N4c1c(-c3ccccc3)cccc1-c1ccccc1)Oc1cc(-c3ccccc3)cc3c1B2c1ccccc1O3] 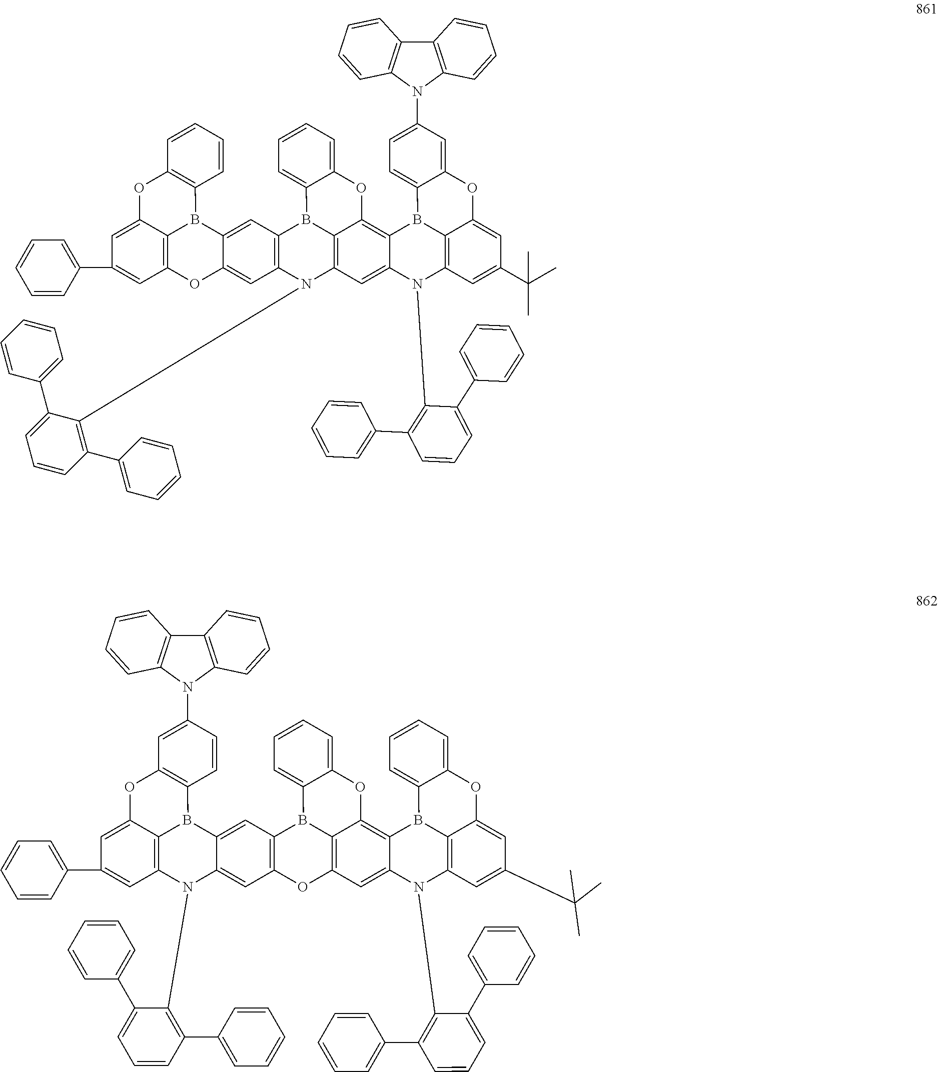 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)Oc1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccccc1O2)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3] 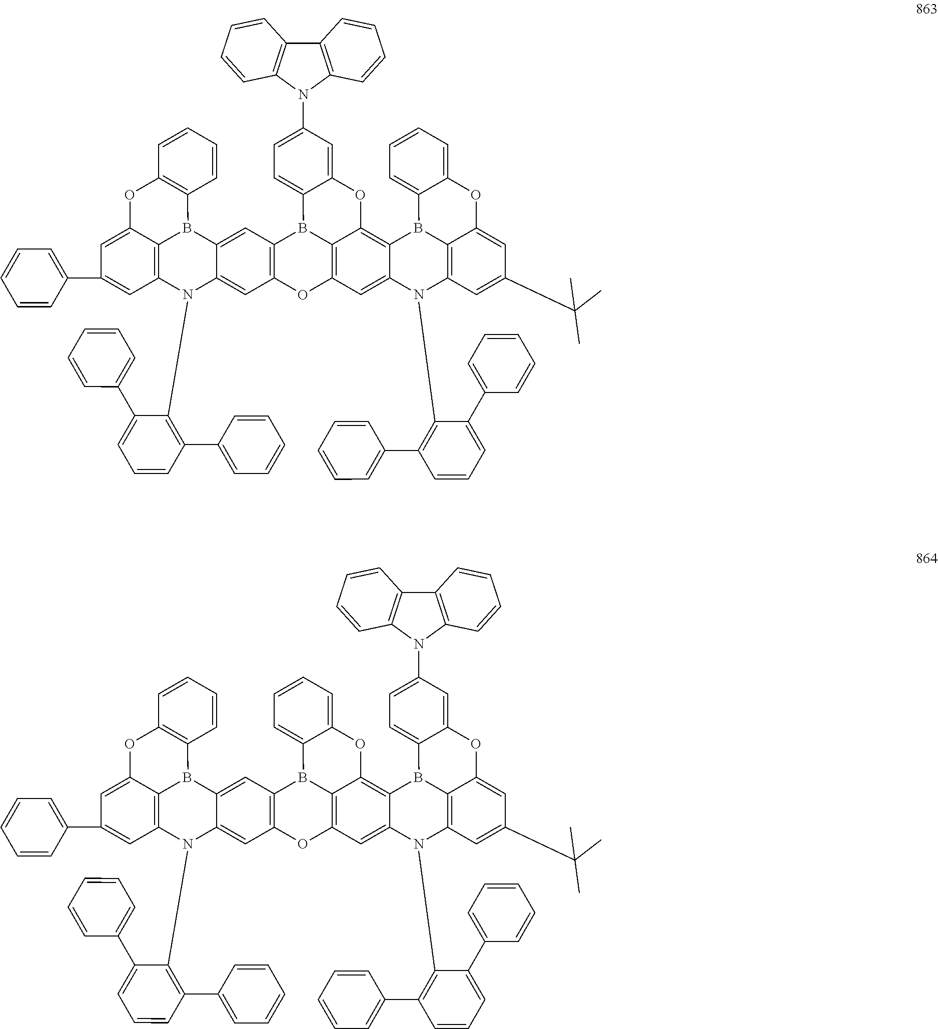 [SMILES: CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccccc1O3] 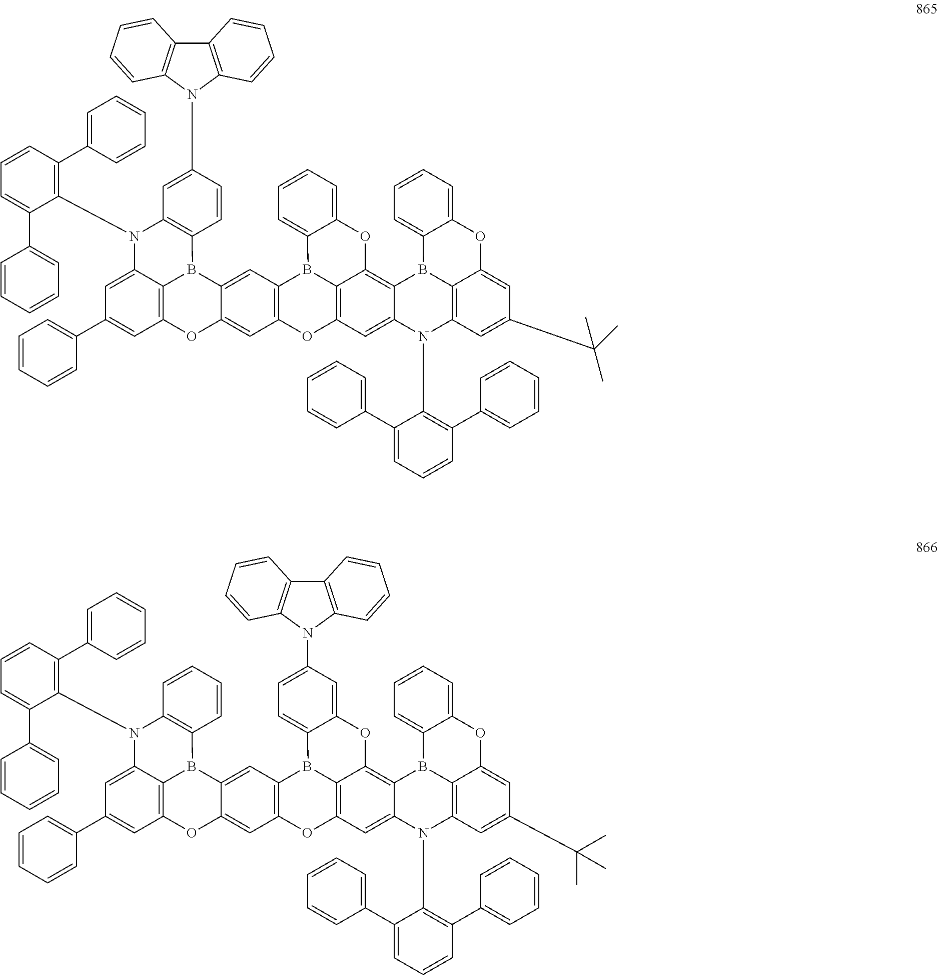 [SMILES: CC(C)(C)c1cc2c3c(c1)N(c1c(-c4ccccc4)cccc1-c1ccccc1)c1cc4c5c(c1B3c1ccccc1O2)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1O4)Oc1cc(-c3ccccc3)cc3c1B2c1ccccc1N3c1c(-c2ccccc2)cccc1-c1ccccc1] 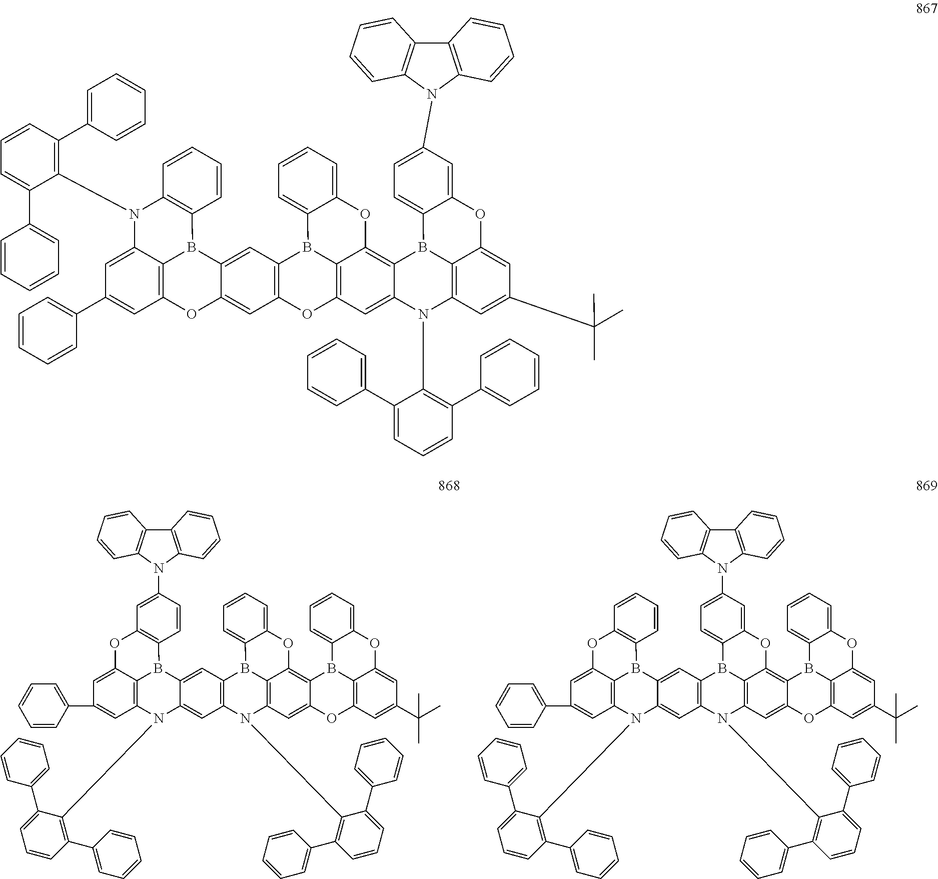 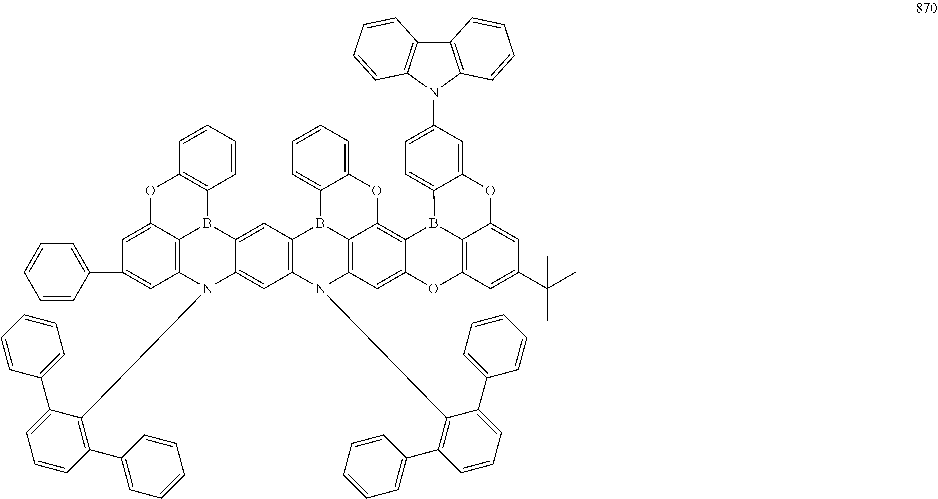 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccccc1O3] 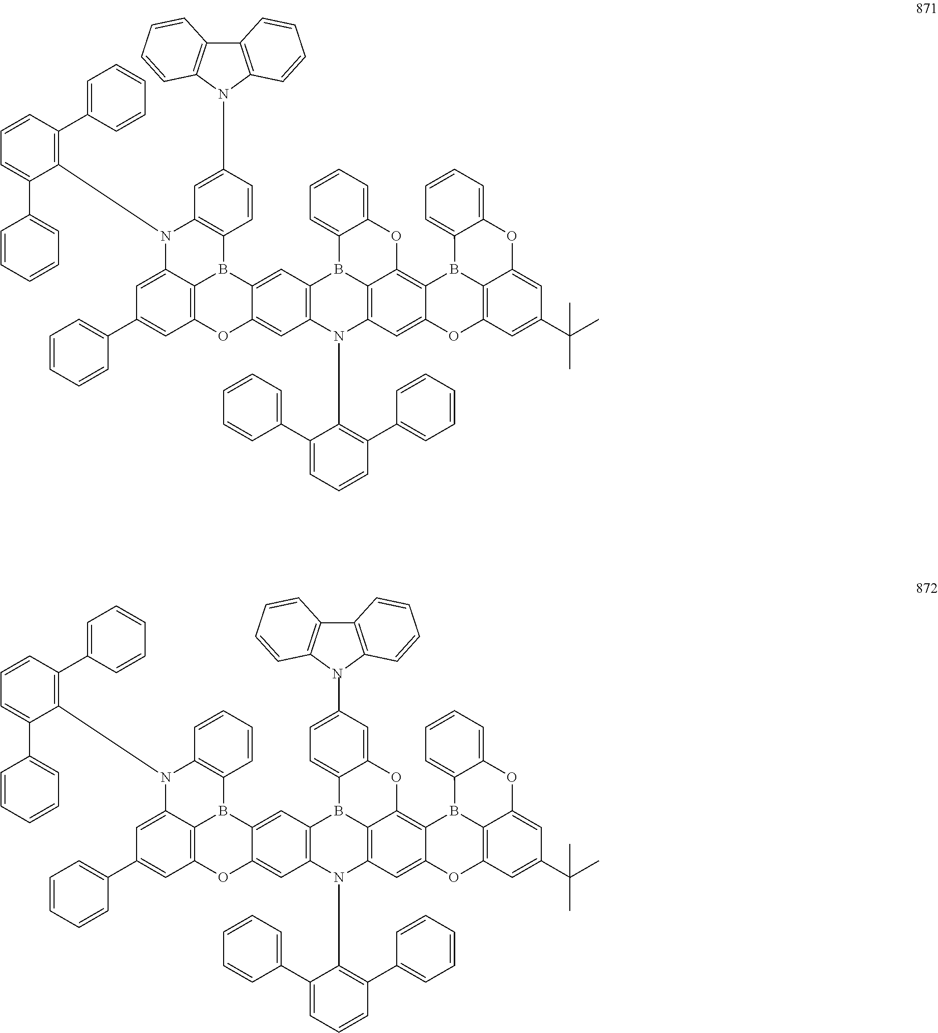 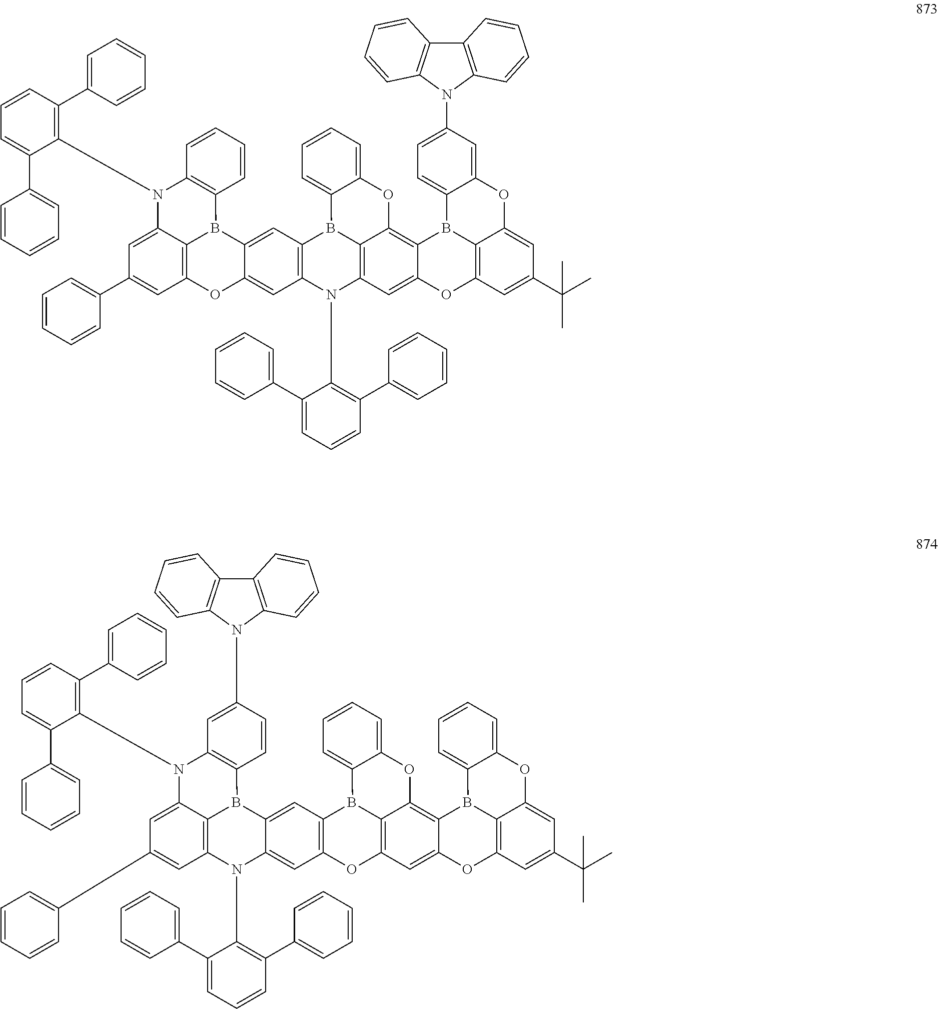 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)Oc1cc(-c3ccccc3)cc3c1B2c1ccccc1N3c1c(-c2ccccc2)cccc1-c1ccccc1 ; CC(C)(C)c1cc2c3c(c1)Oc1cc4c5c(c1B3c1ccccc1O2)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1] 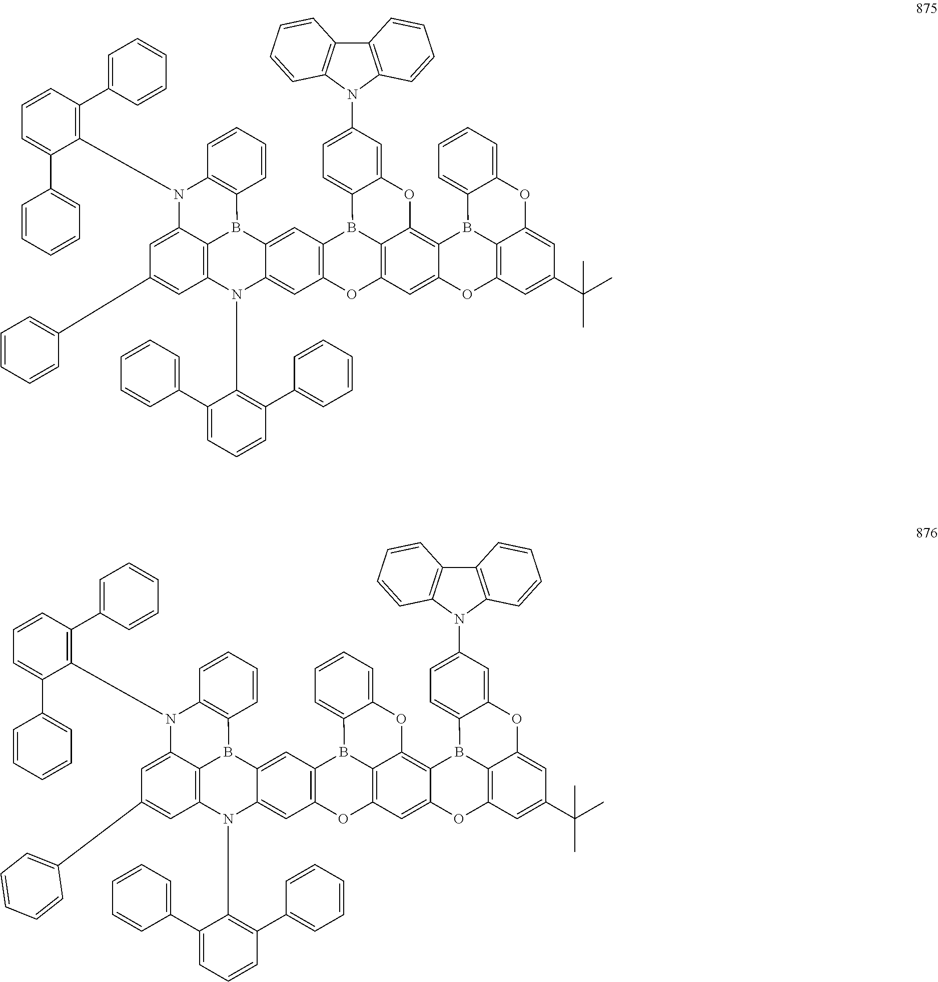 [SMILES: CC(C)(C)c1cc2c3c(c1)Oc1cc4c5c(c1B3c1ccccc1O2)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1] 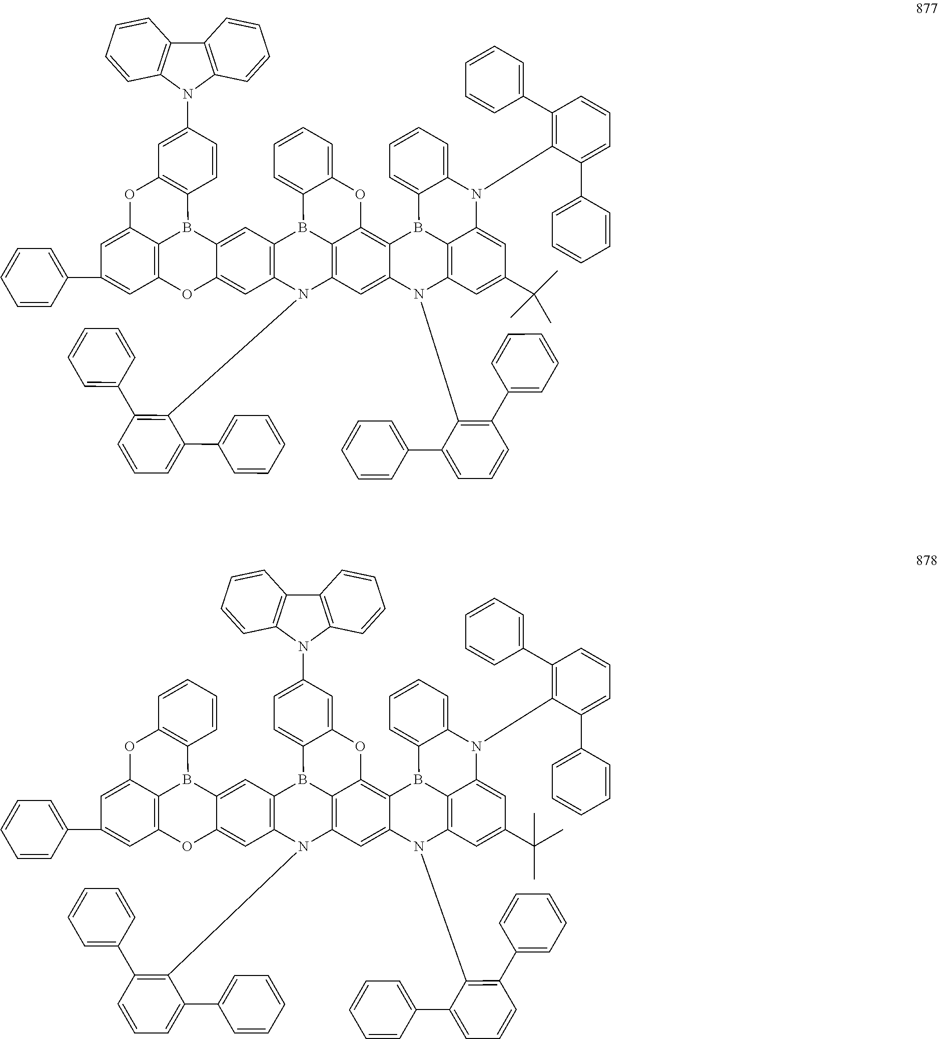 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1N4c1c(-c3ccccc3)cccc1-c1ccccc1)Oc1cc(-c3ccccc3)cc3c1B2c1ccccc1O3] 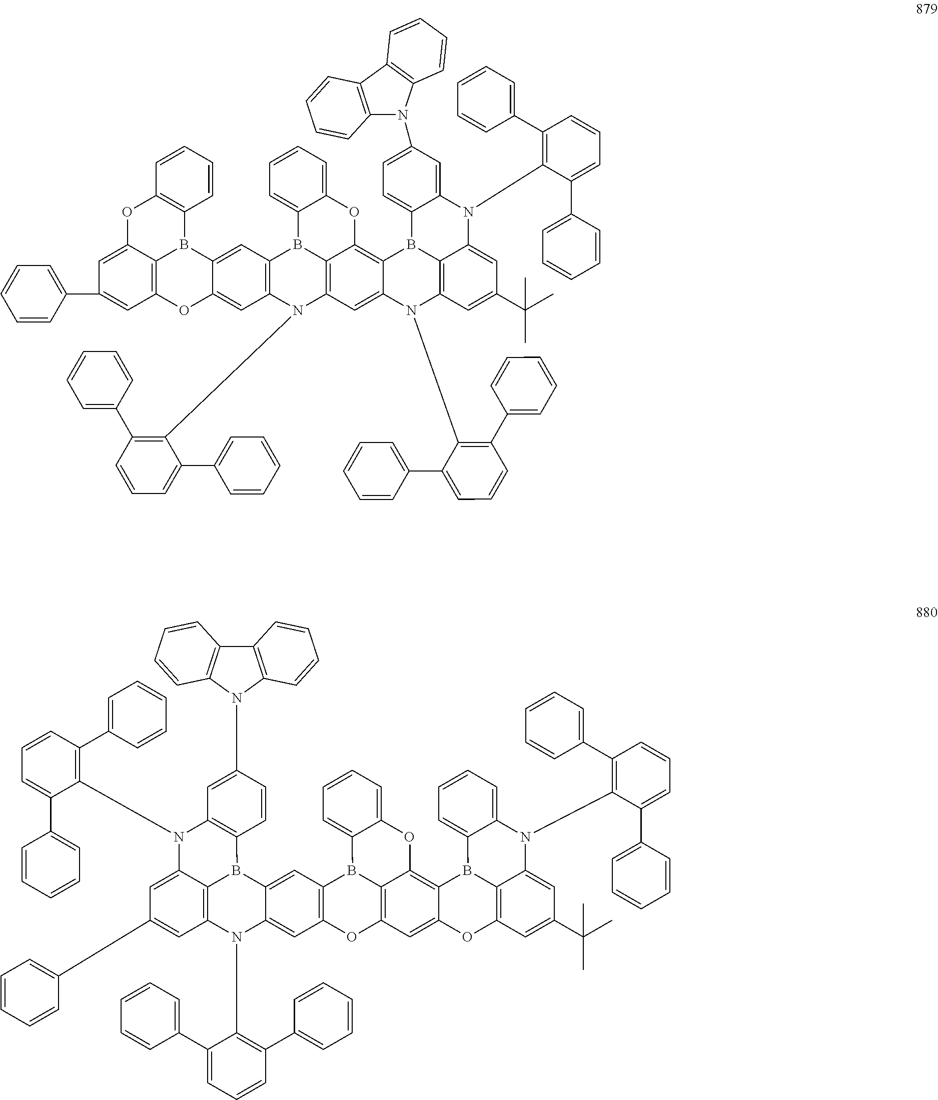 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccccc1O3 ; CC(C)(C)c1cc2c3c(c1)N(c1c(-c4ccccc4)cccc1-c1ccccc1)c1ccccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1N3c1c(-c3ccccc3)cccc1-c1ccccc1)O2] 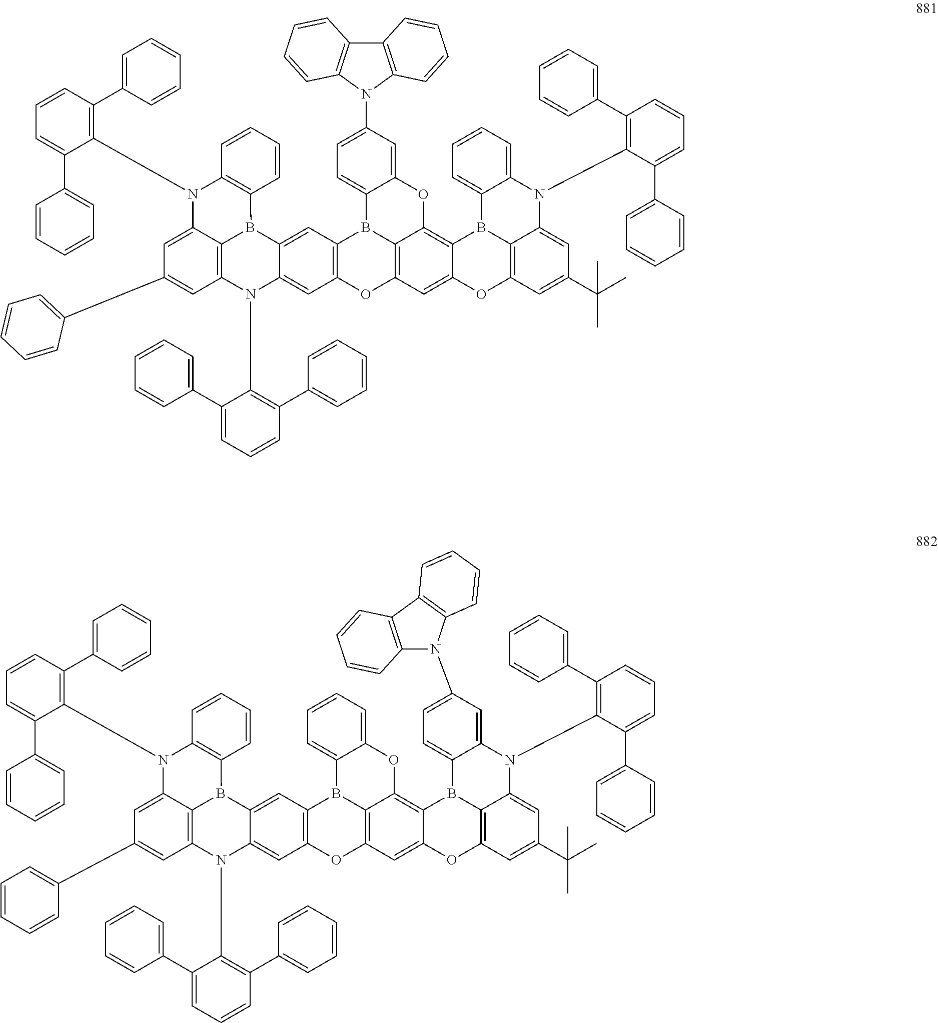 [SMILES: CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1O3)N(c1c(-c3ccccc3)cccc1-c1ccccc1)c1cc(-c3ccccc3)cc3c1B4c1ccccc1N3c1c(-c3ccccc3)cccc1-c1ccccc1)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccccc1N3c1c(-c3ccccc3)cccc1-c1ccccc1)O2] 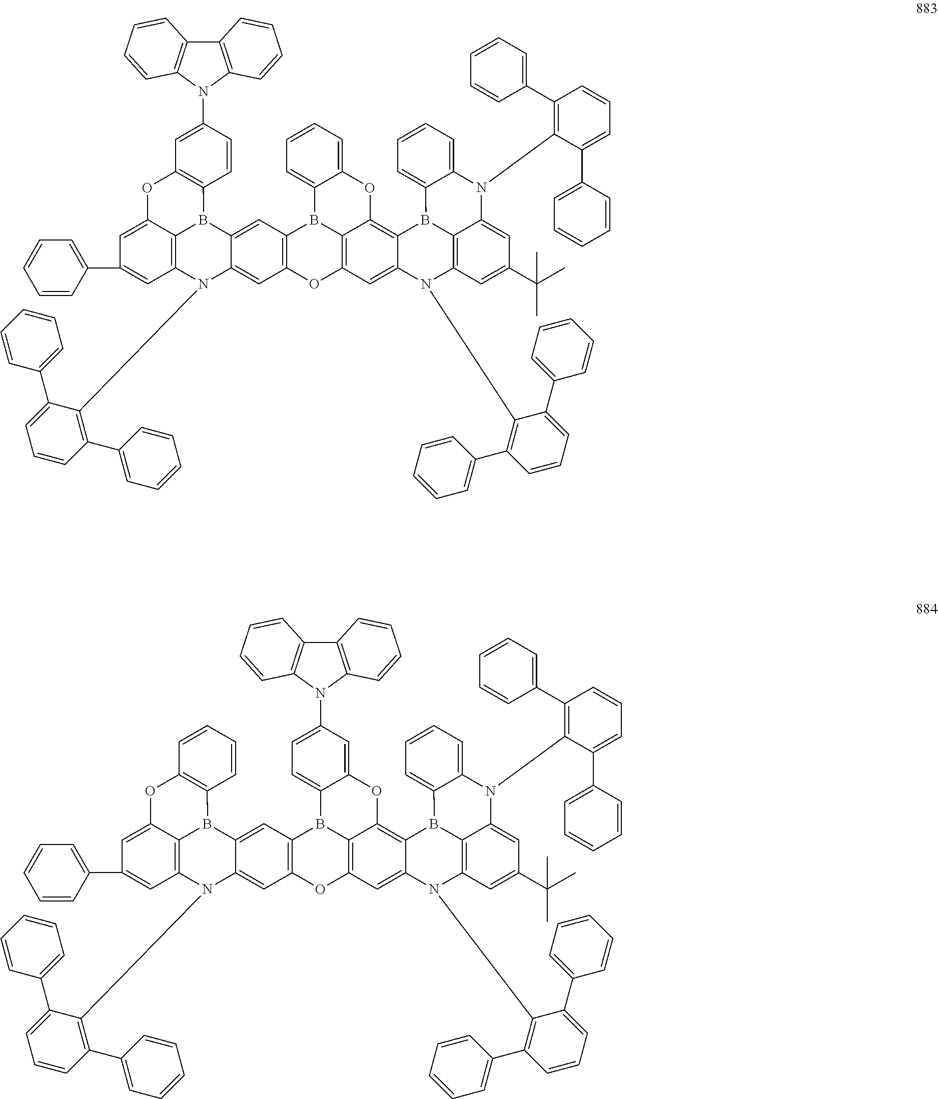 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1O3] 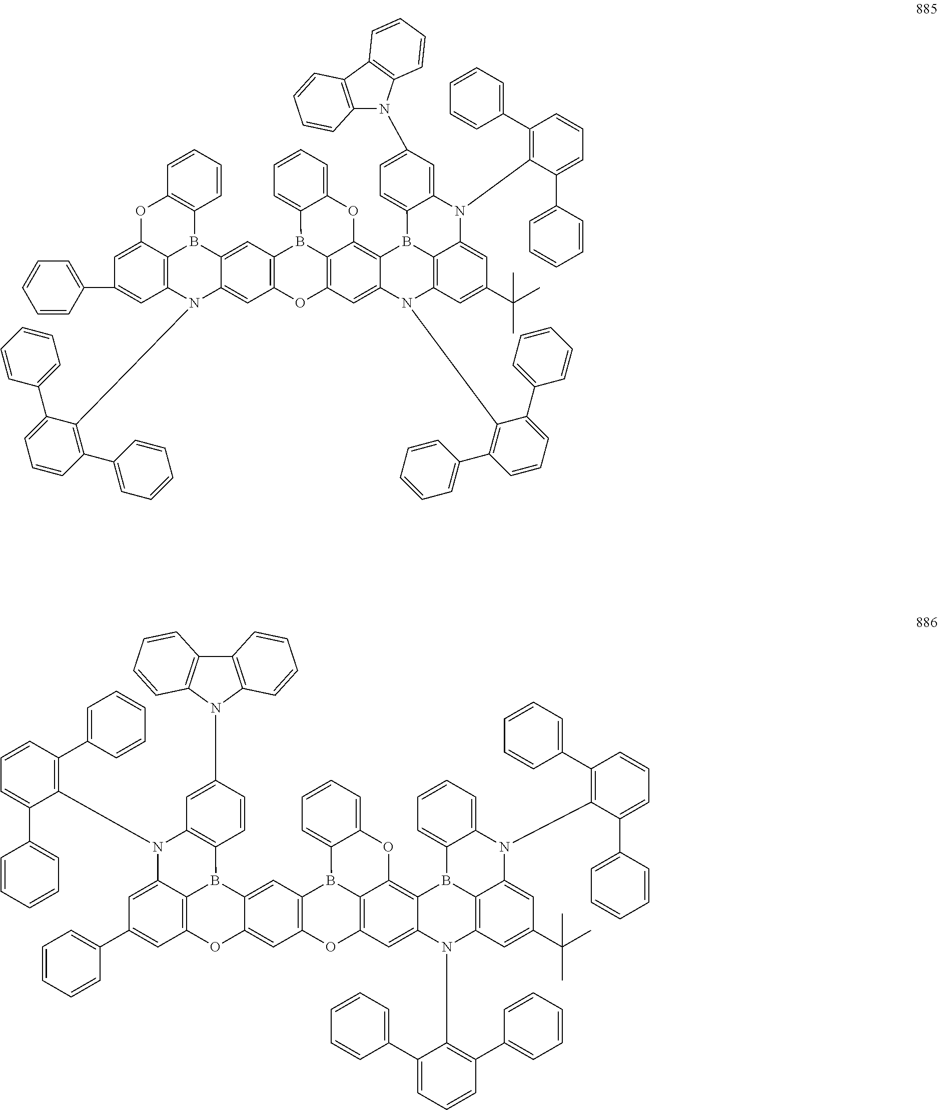 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1] 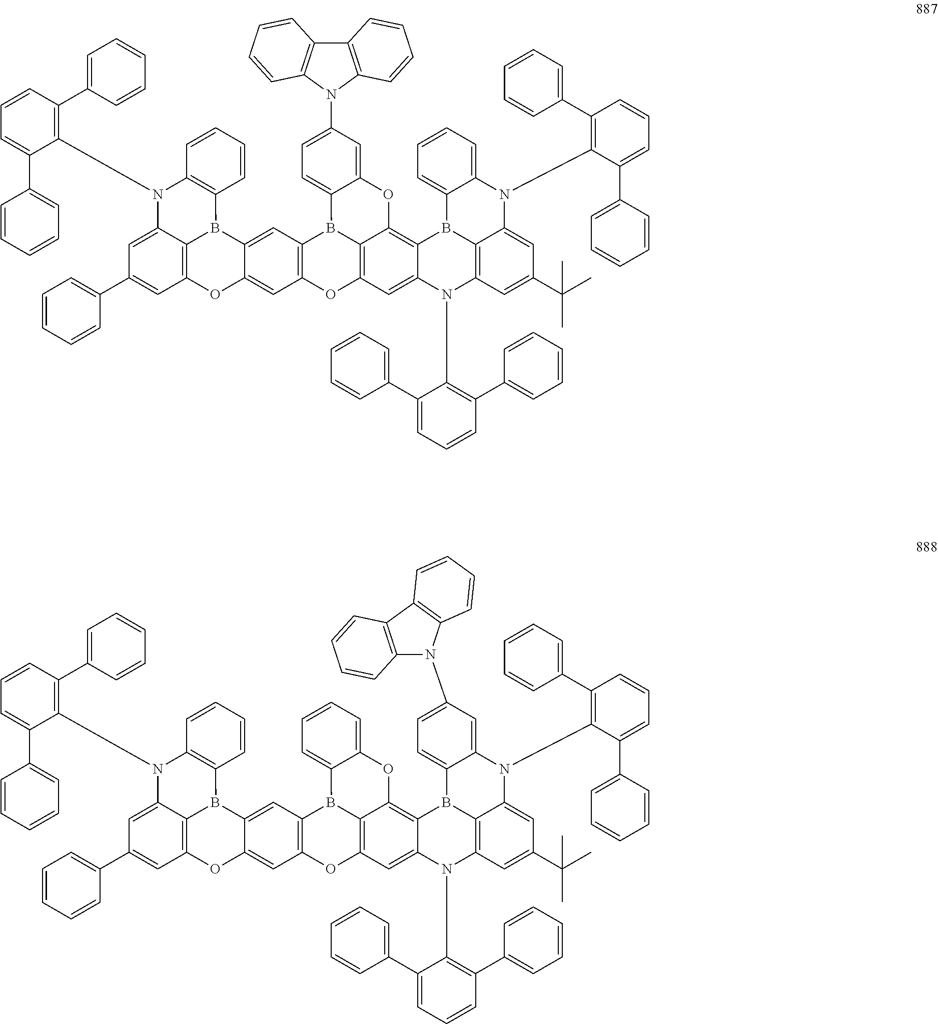 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1O4)Oc1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)Oc1cc(-c3ccccc3)cc3c1B2c1ccccc1N3c1c(-c2ccccc2)cccc1-c1ccccc1] 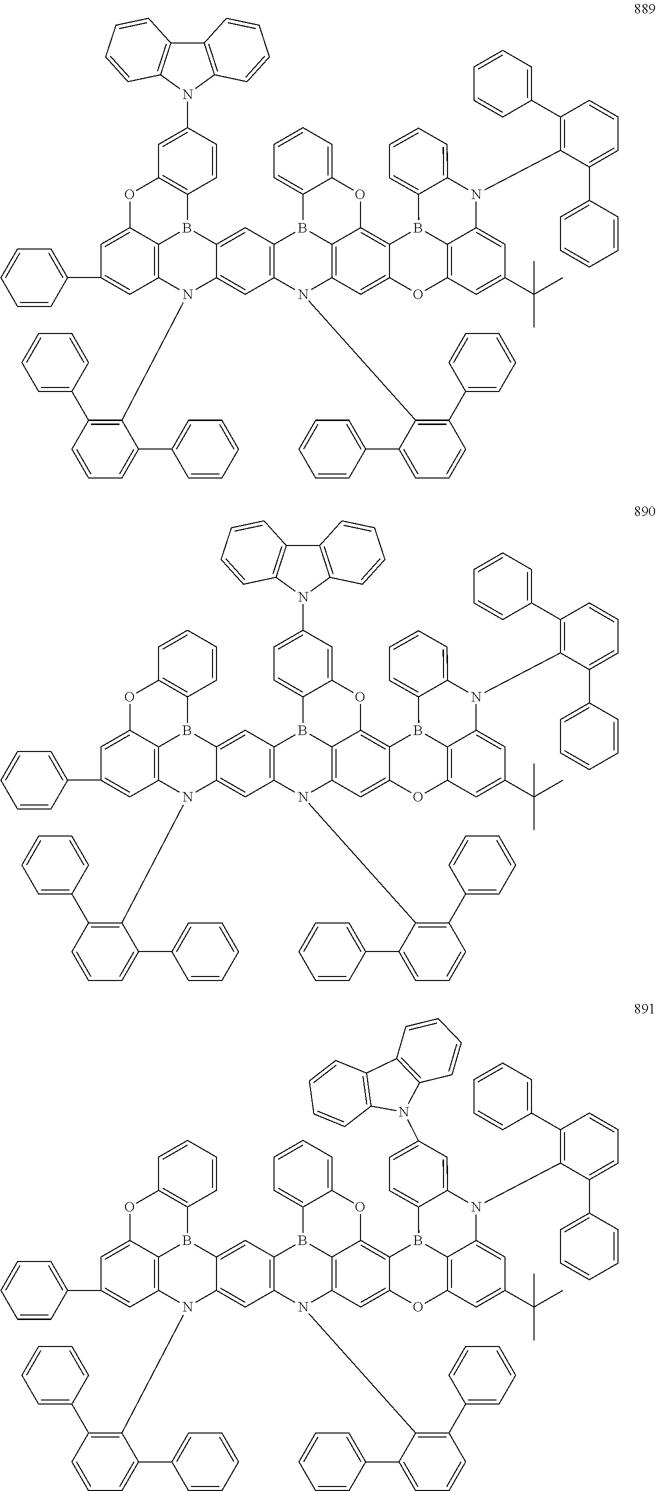 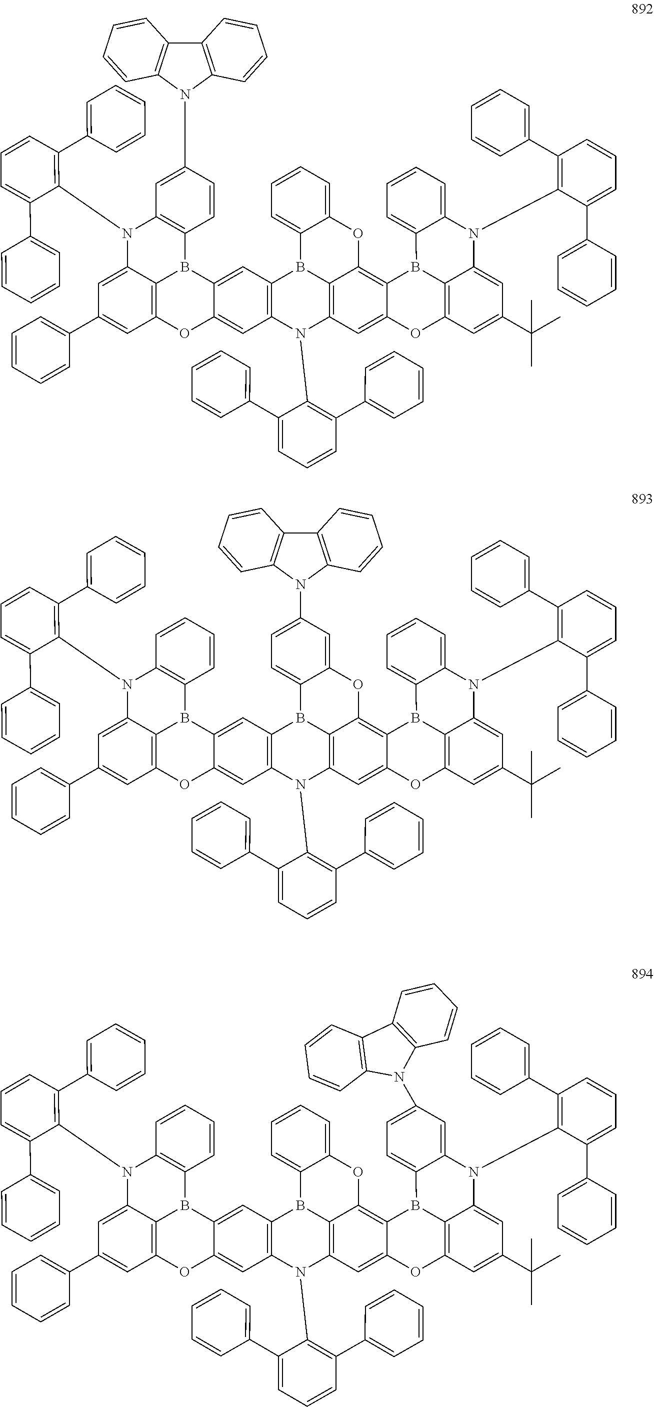 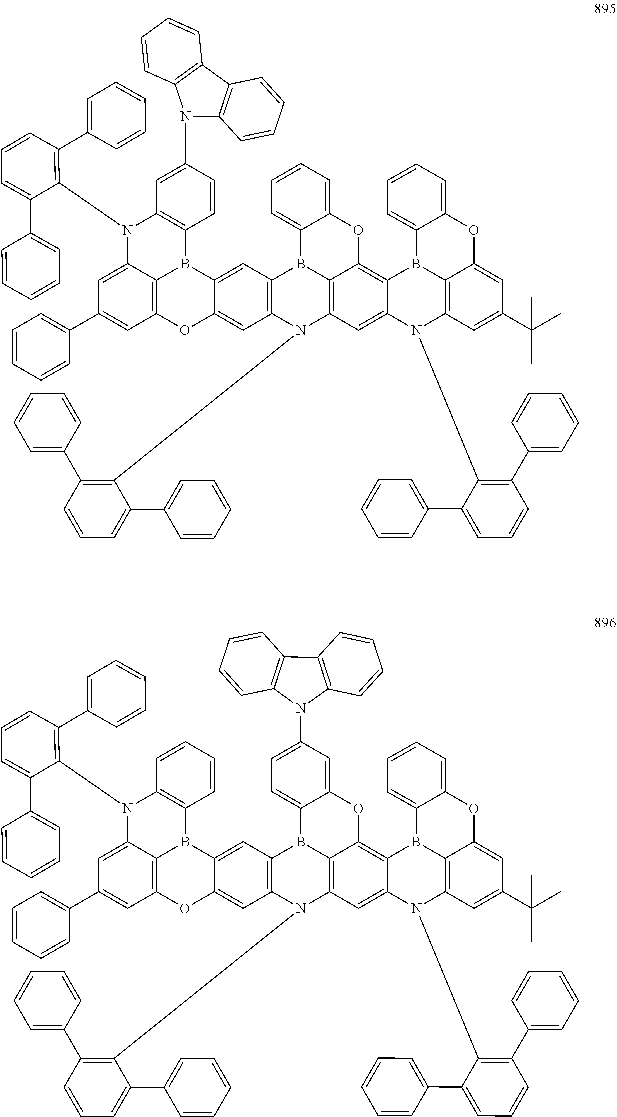 [SMILES: CC(C)(C)c1cc2c3c(c1)N(c1c(-c4ccccc4)cccc1-c1ccccc1)c1cc4c5c(c1B3c1ccccc1O2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1N4c1c(-c3ccccc3)cccc1-c1ccccc1)Oc1cc(-c3ccccc3)cc3c1B2c1ccccc1N3c1c(-c2ccccc2)cccc1-c1ccccc1] 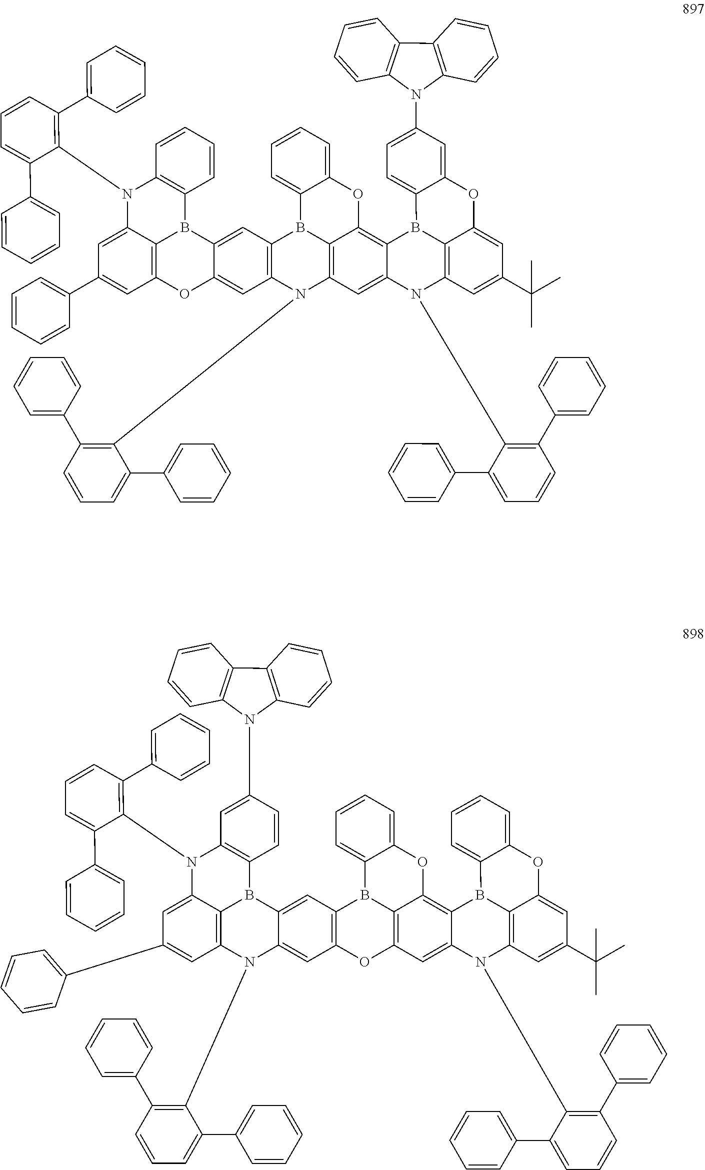 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)Oc1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1] 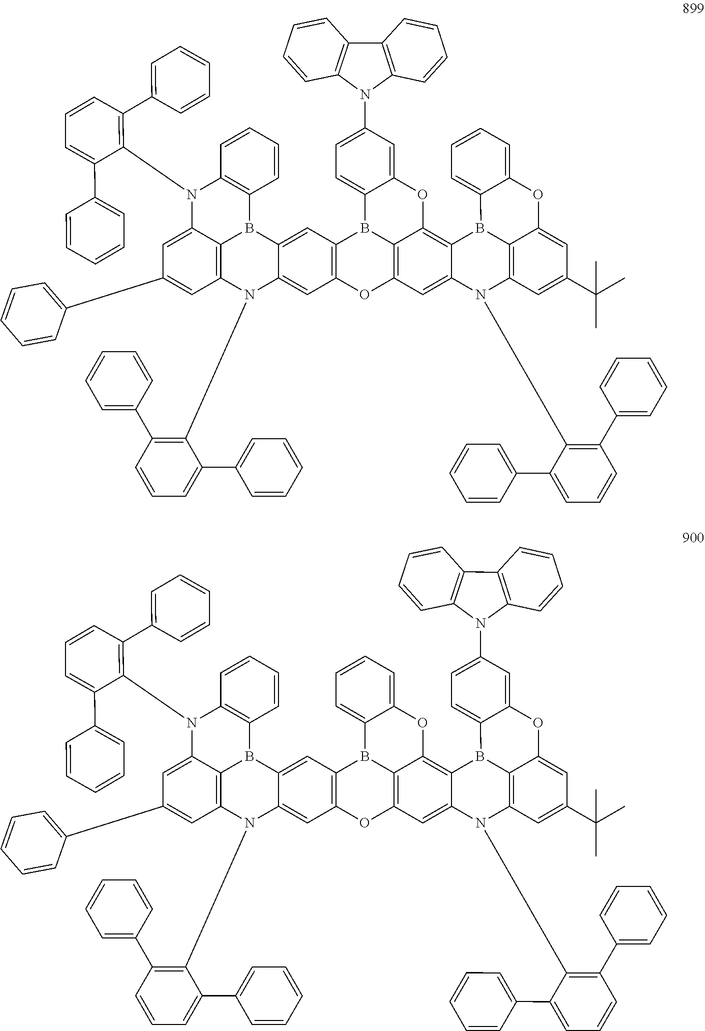 [SMILES: CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1] 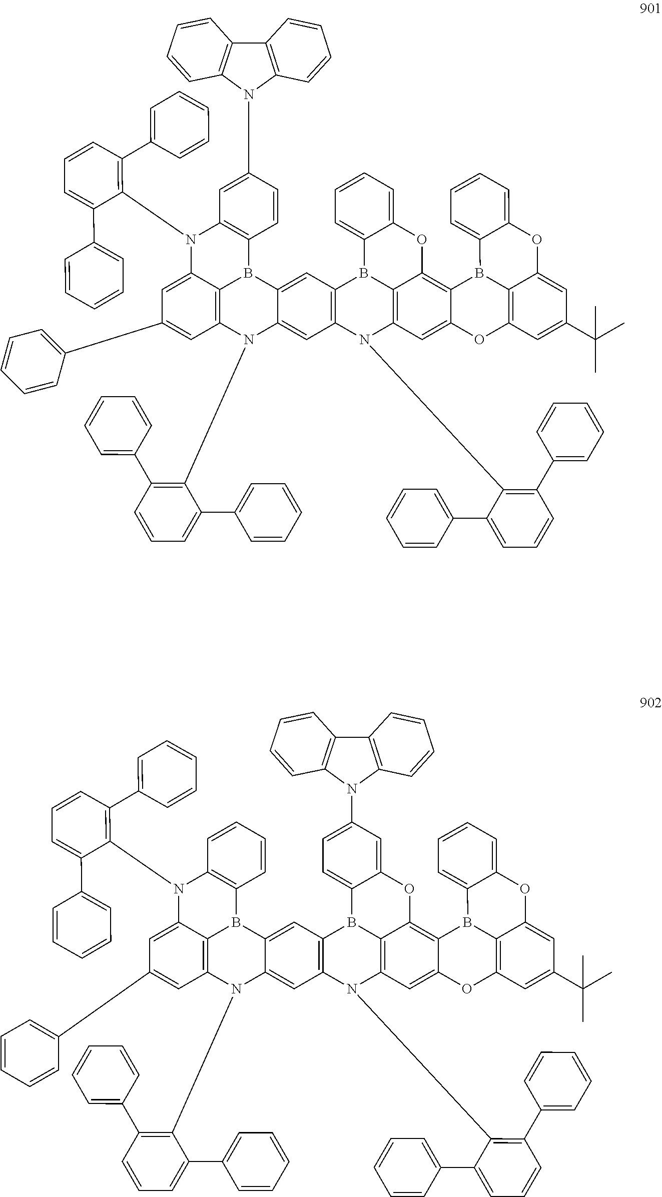 [SMILES: CC(C)(C)c1cc2c3c(c1)Oc1cc4c5c(c1B3c1ccccc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccccc1O2)Oc1cc(-n2c3ccccc3c3ccccc32)ccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccccc1N3c1c(-c2ccccc2)cccc1-c1ccccc1] 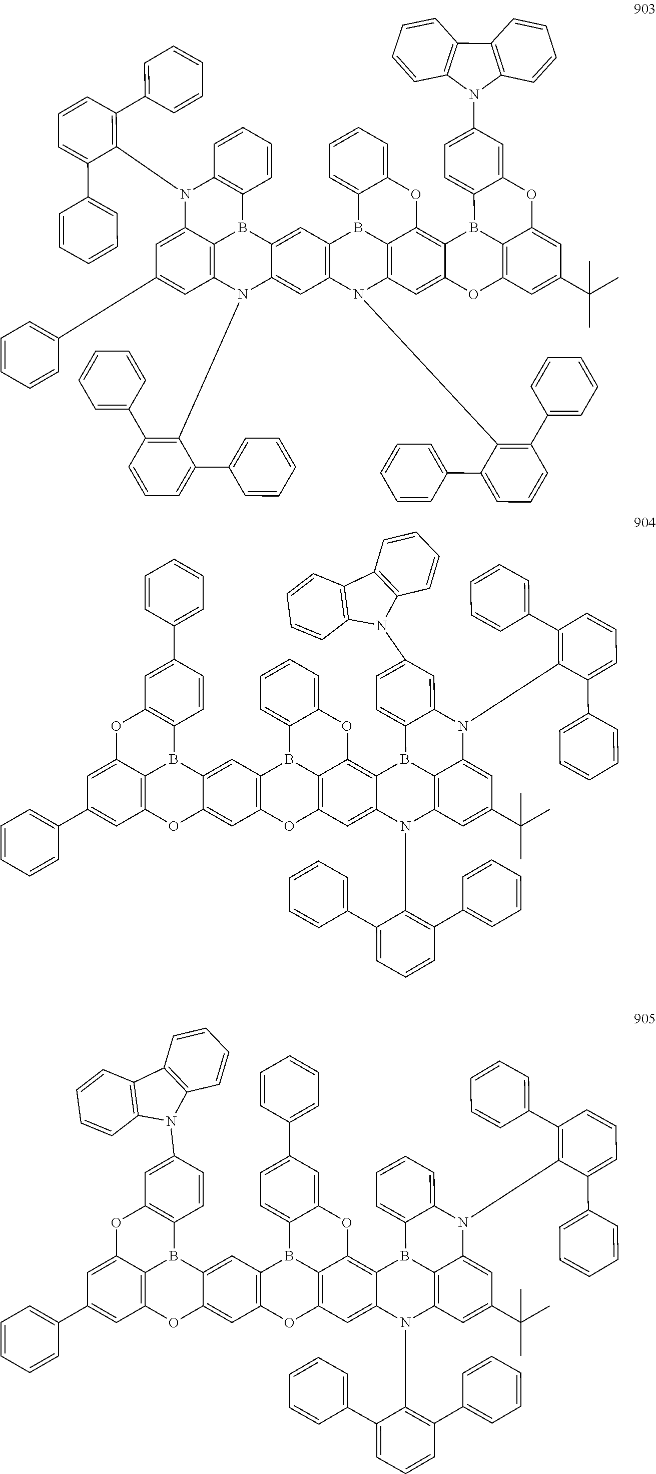 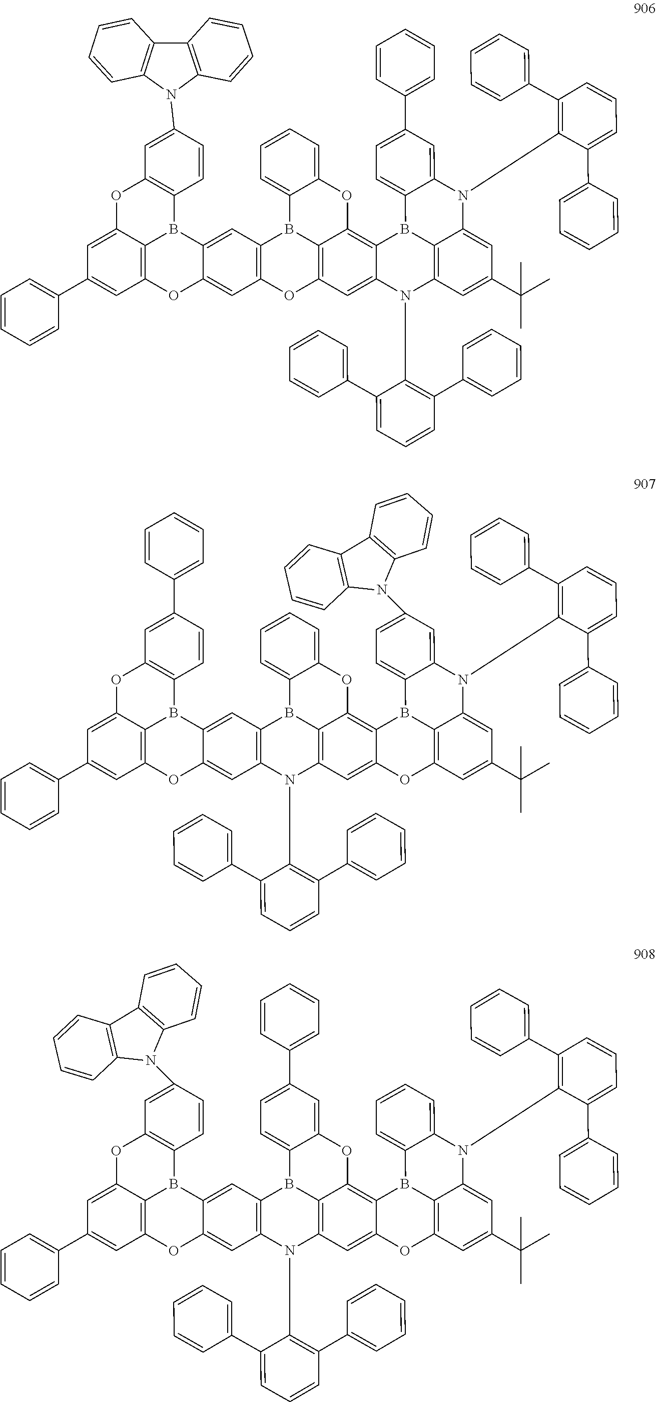 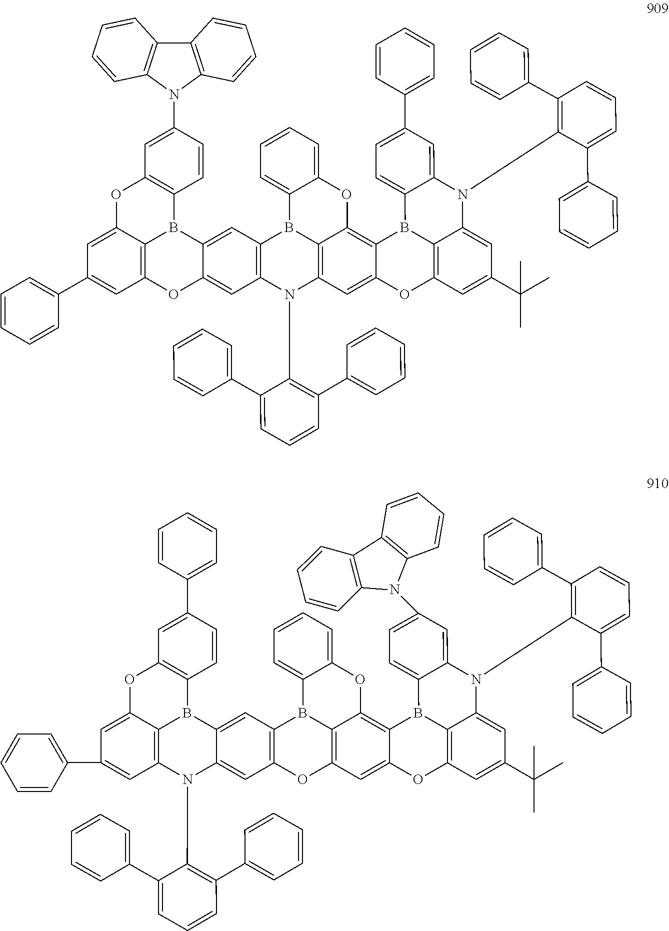 [SMILES: CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-c4ccccc4)cc1O3)O2] 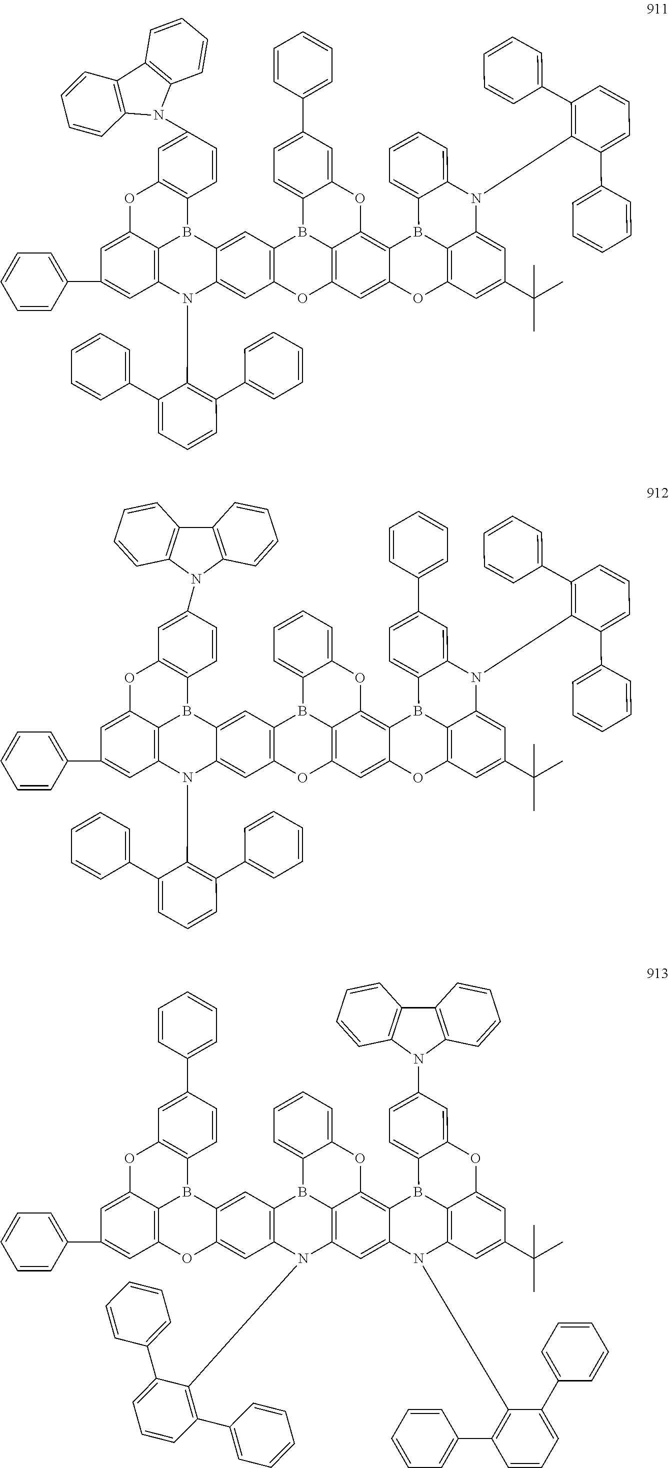 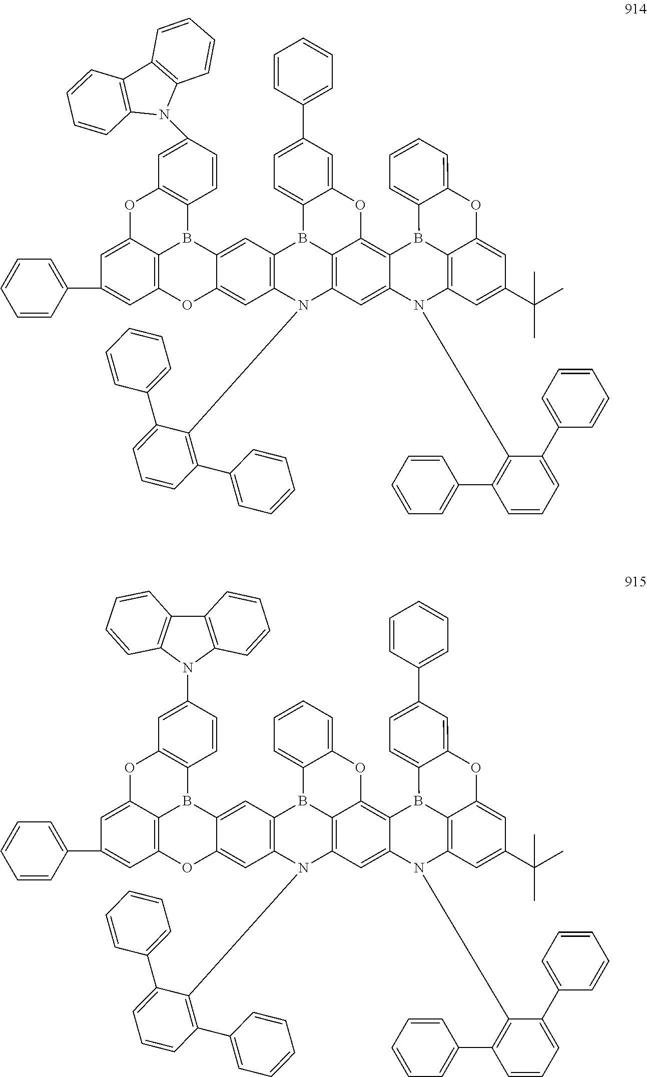 [SMILES: CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3] 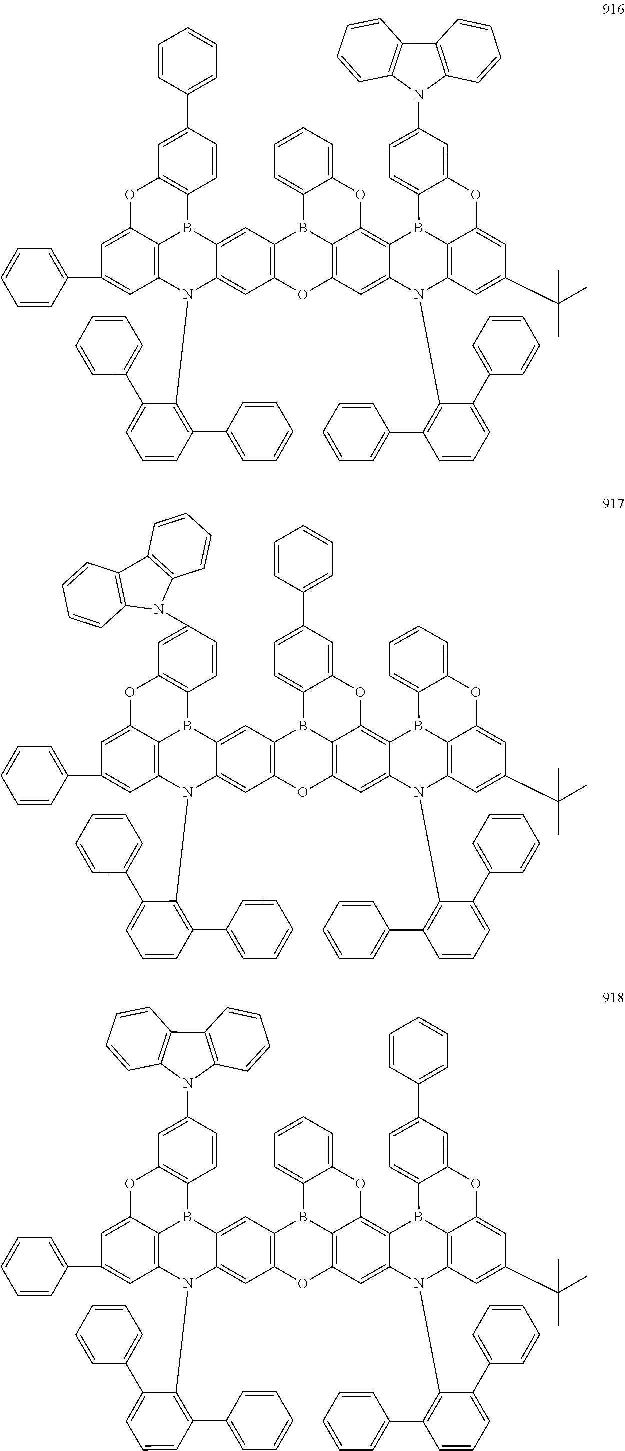 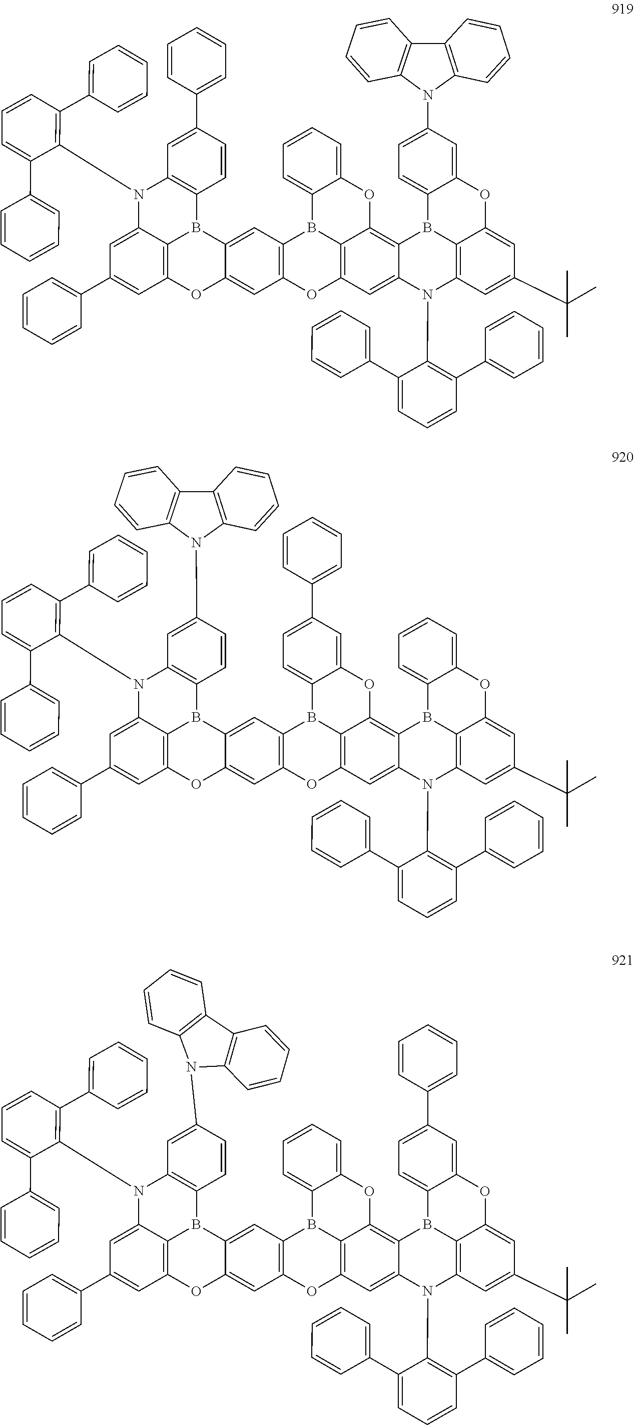 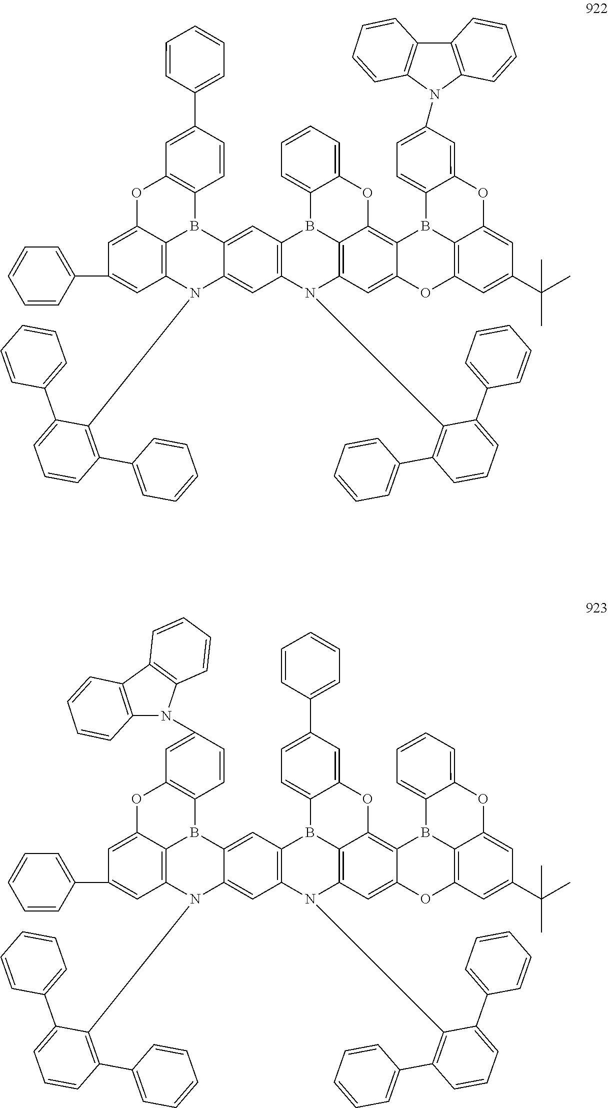 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-c2ccccc2)cc1O3 ; CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1O3] 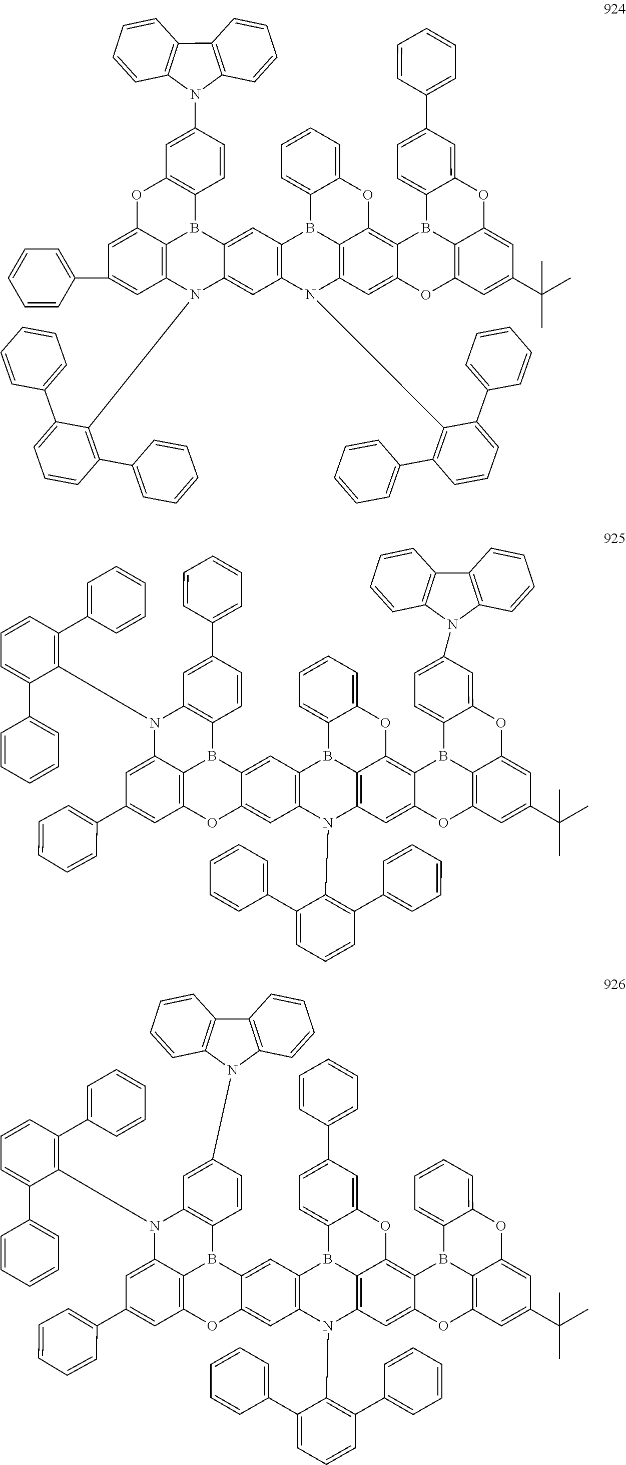 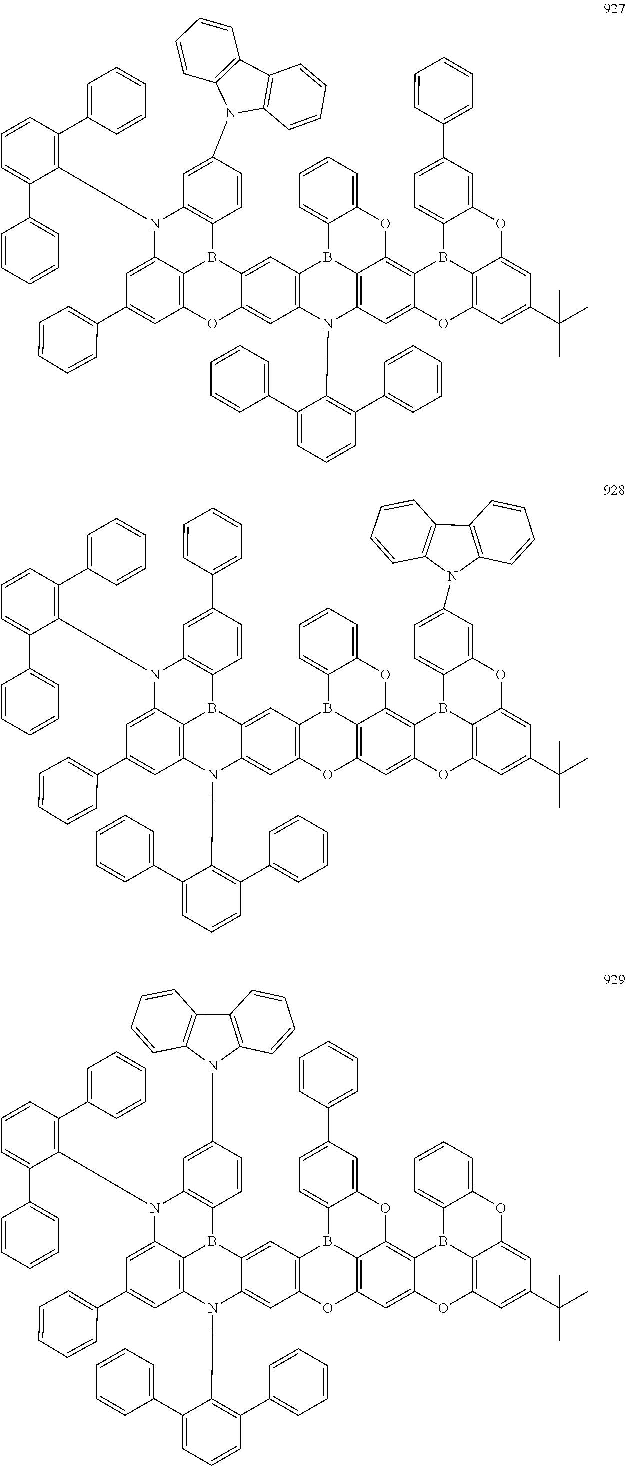 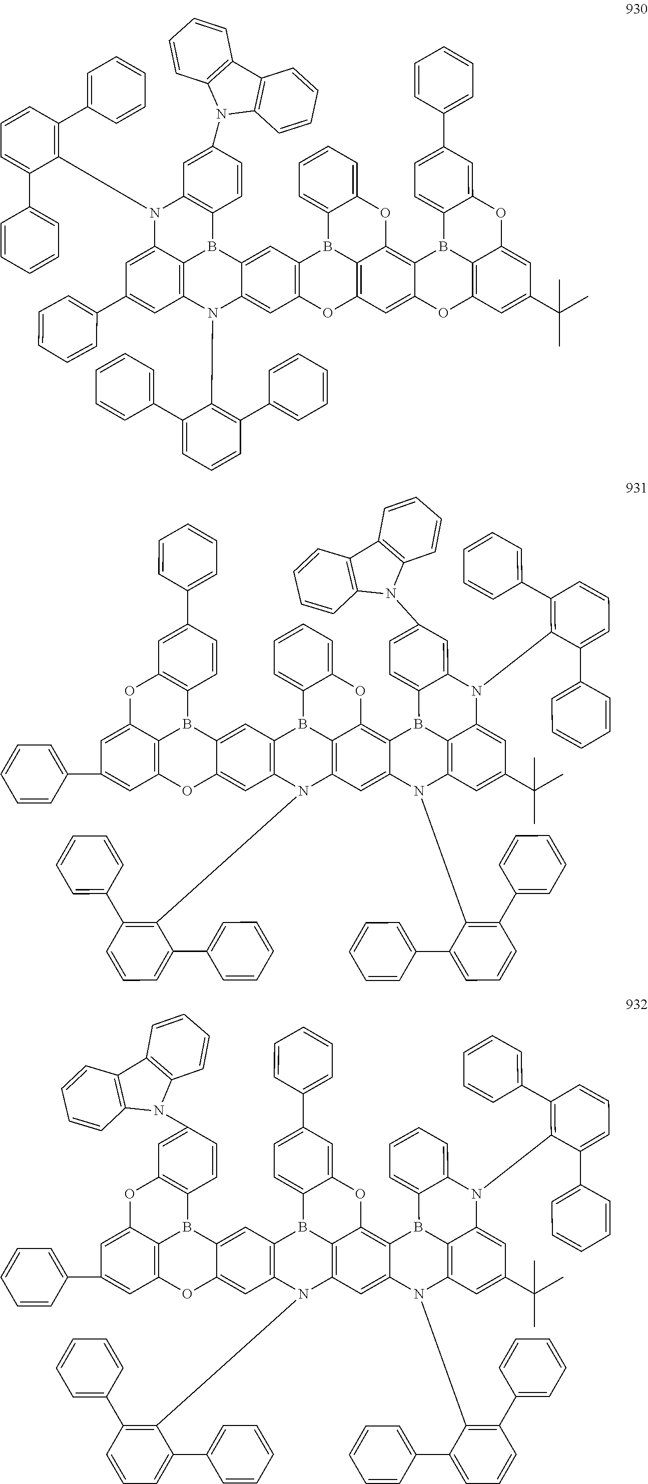 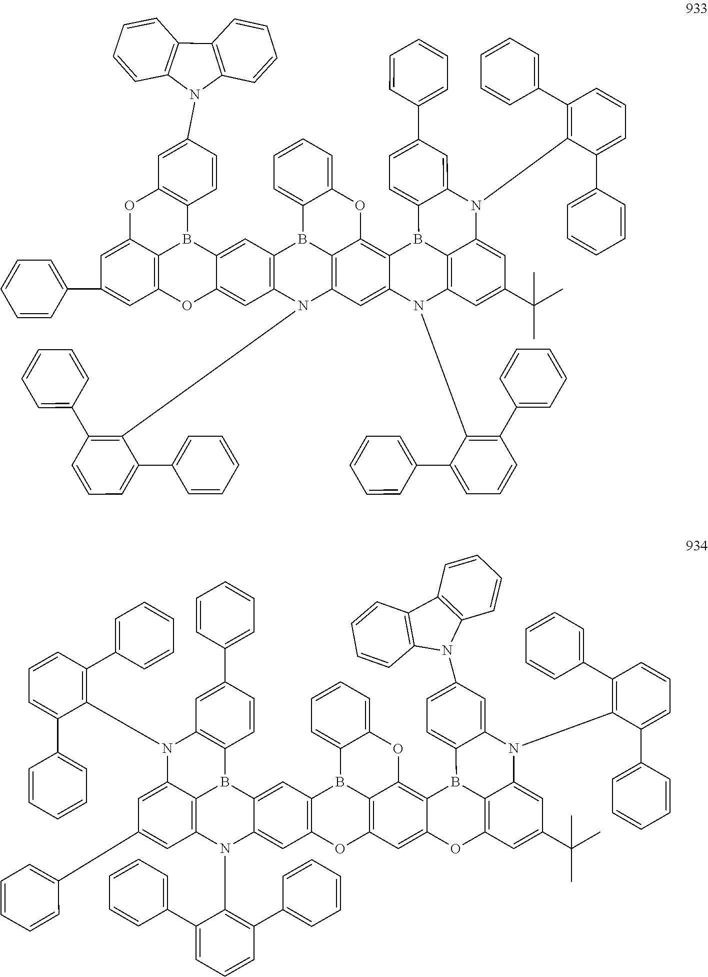 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-c4ccccc4)cc1N3c1c(-c3ccccc3)cccc1-c1ccccc1)O2] 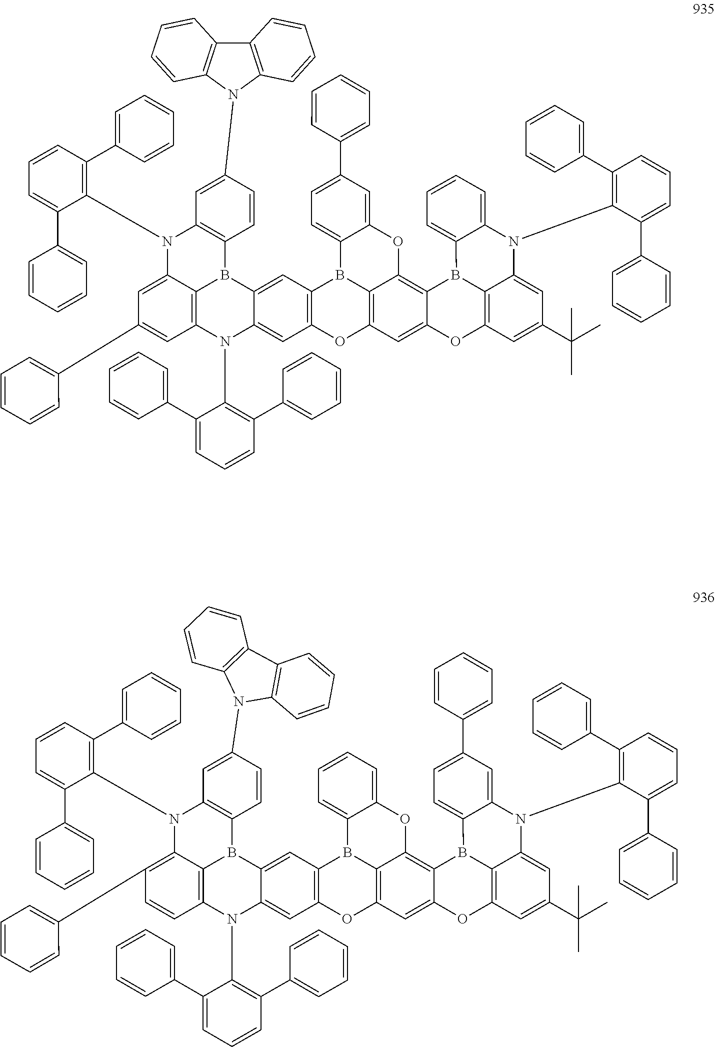 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1N3c1c(-c3ccccc3)cccc1-c1ccccc1)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1O3)N(c1c(-c3ccccc3)cccc1-c1ccccc1)c1ccc(-c3ccccc3)c3c1B4c1ccc(-n4c5ccccc5c5ccccc54)cc1N3c1c(-c3ccccc3)cccc1-c1ccccc1)O2] 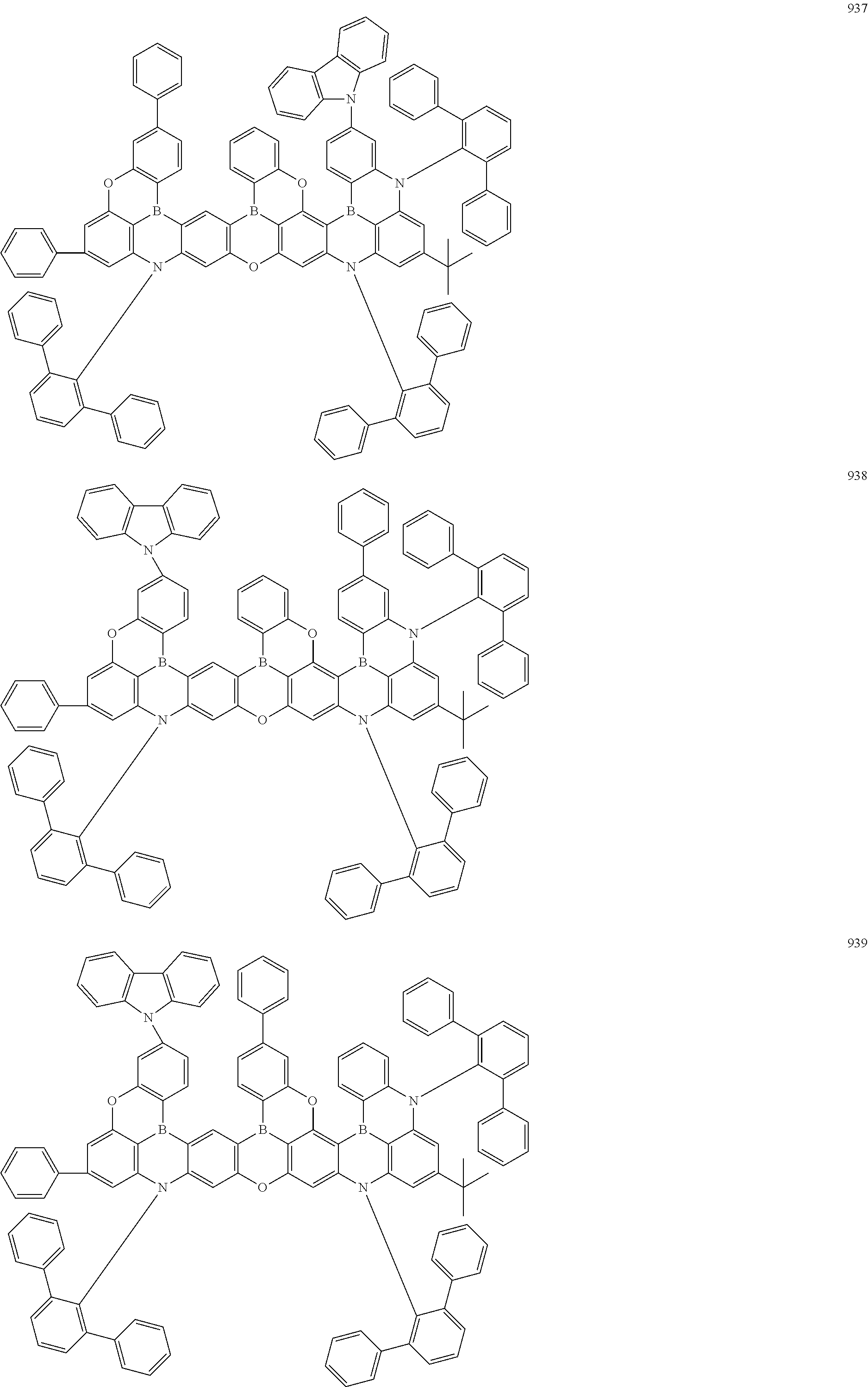 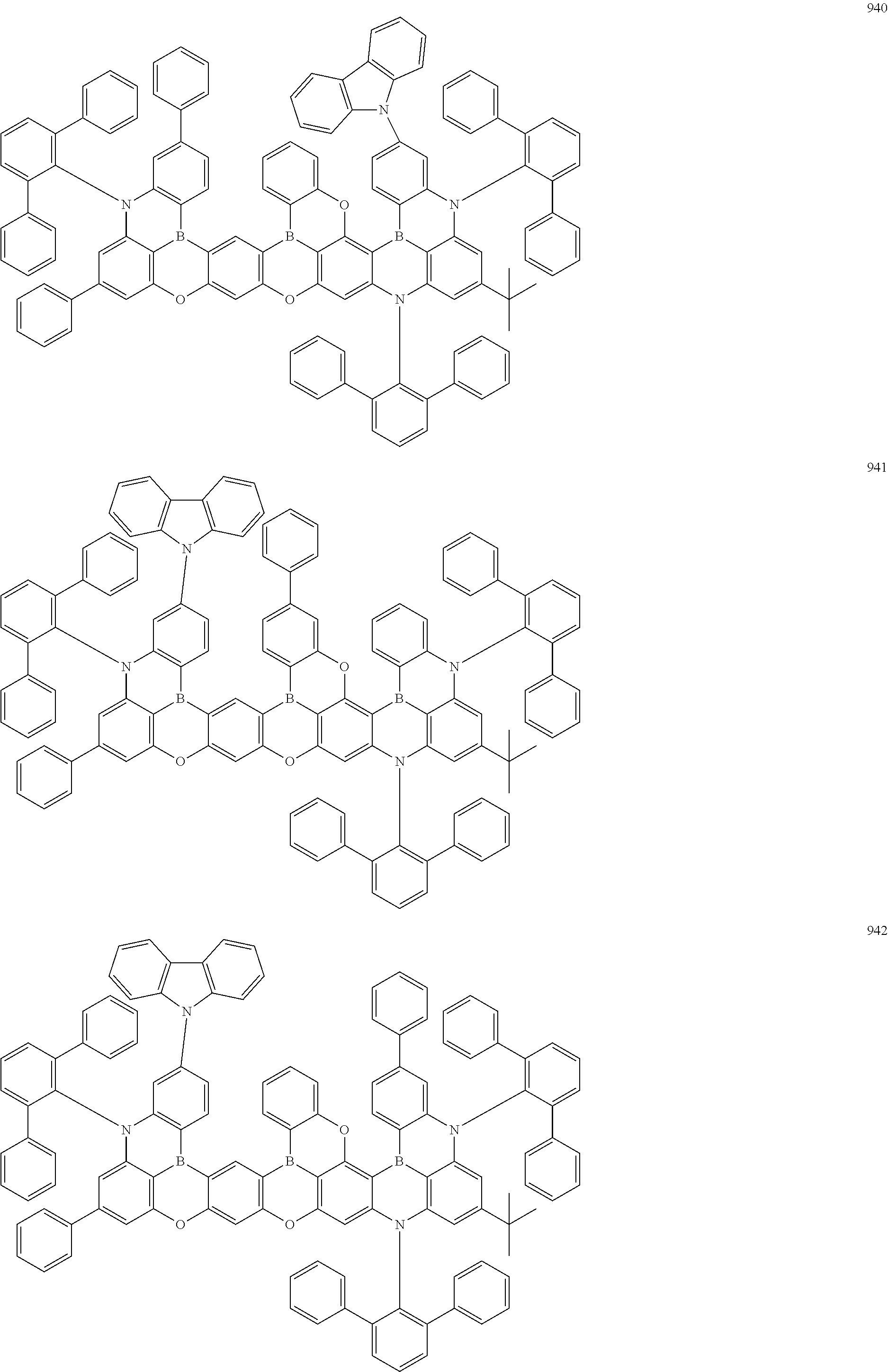 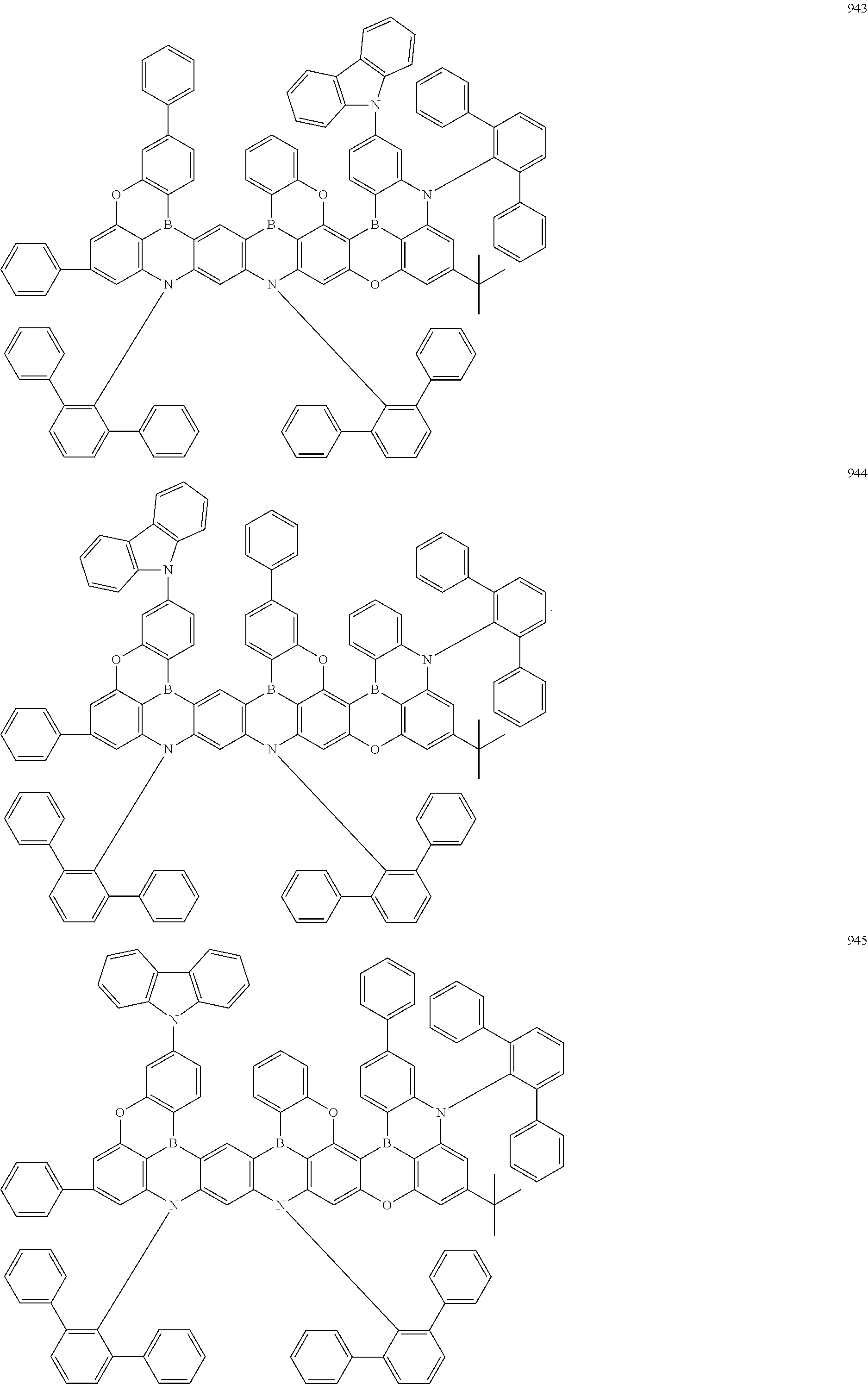 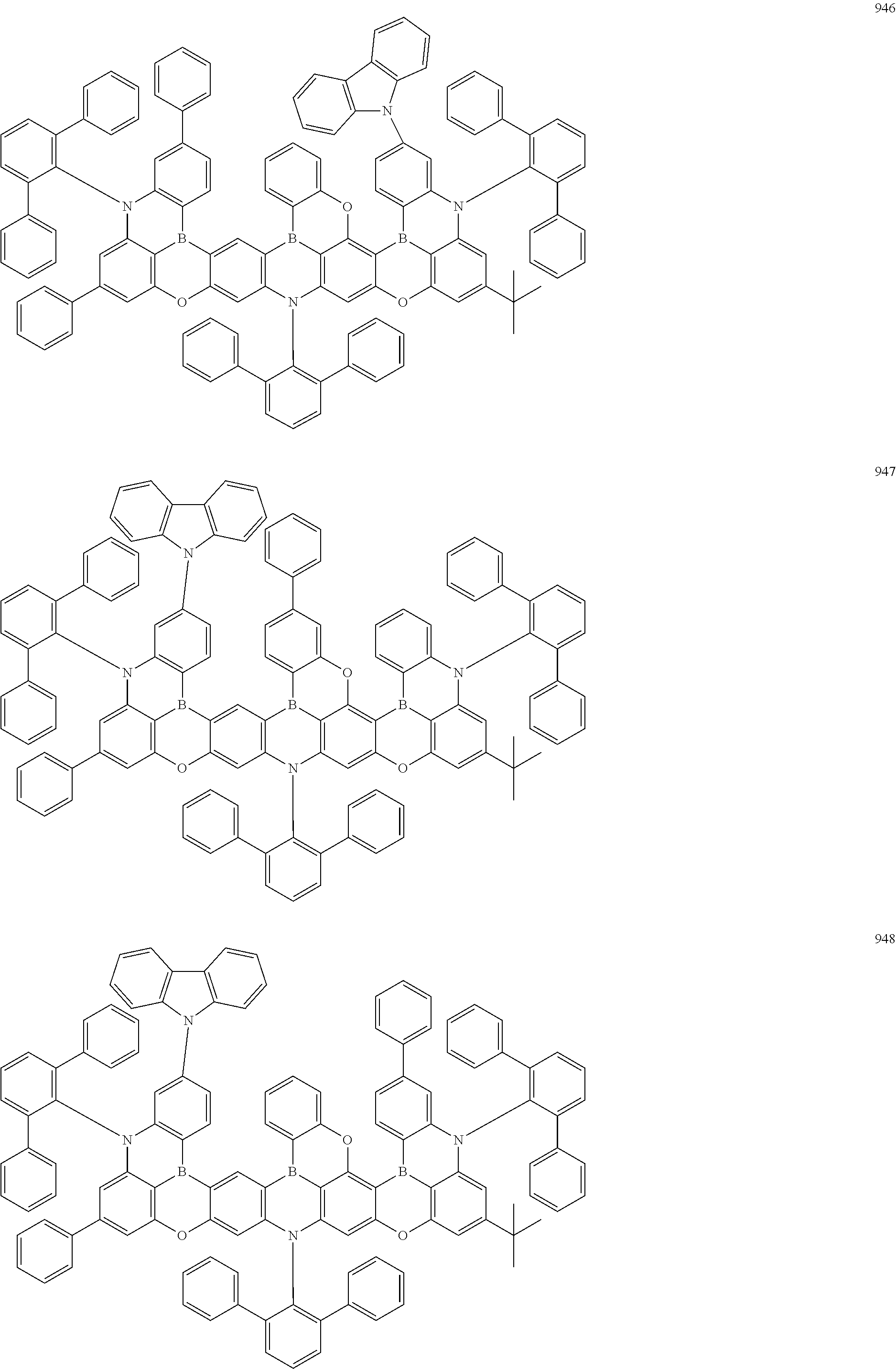 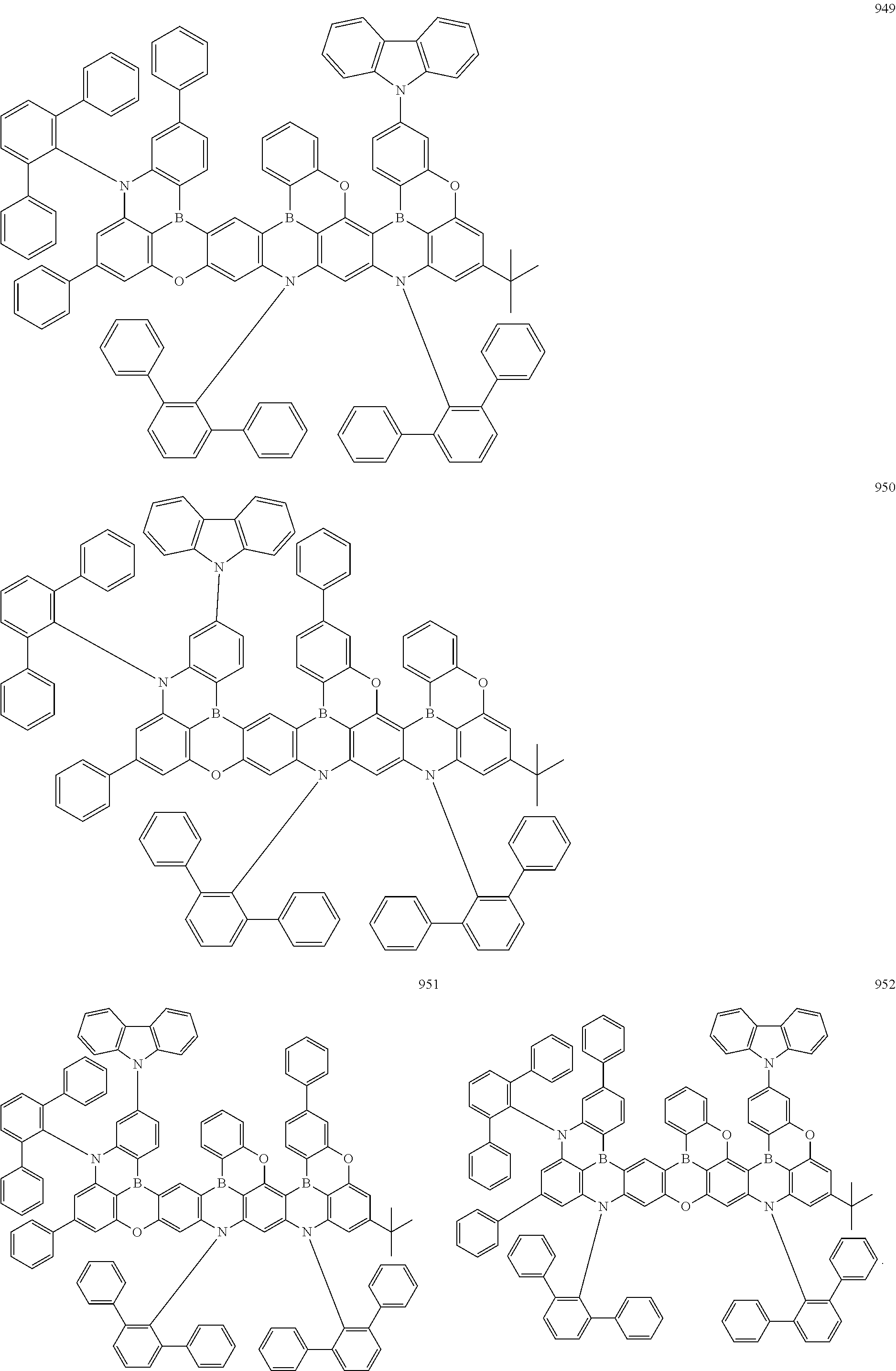 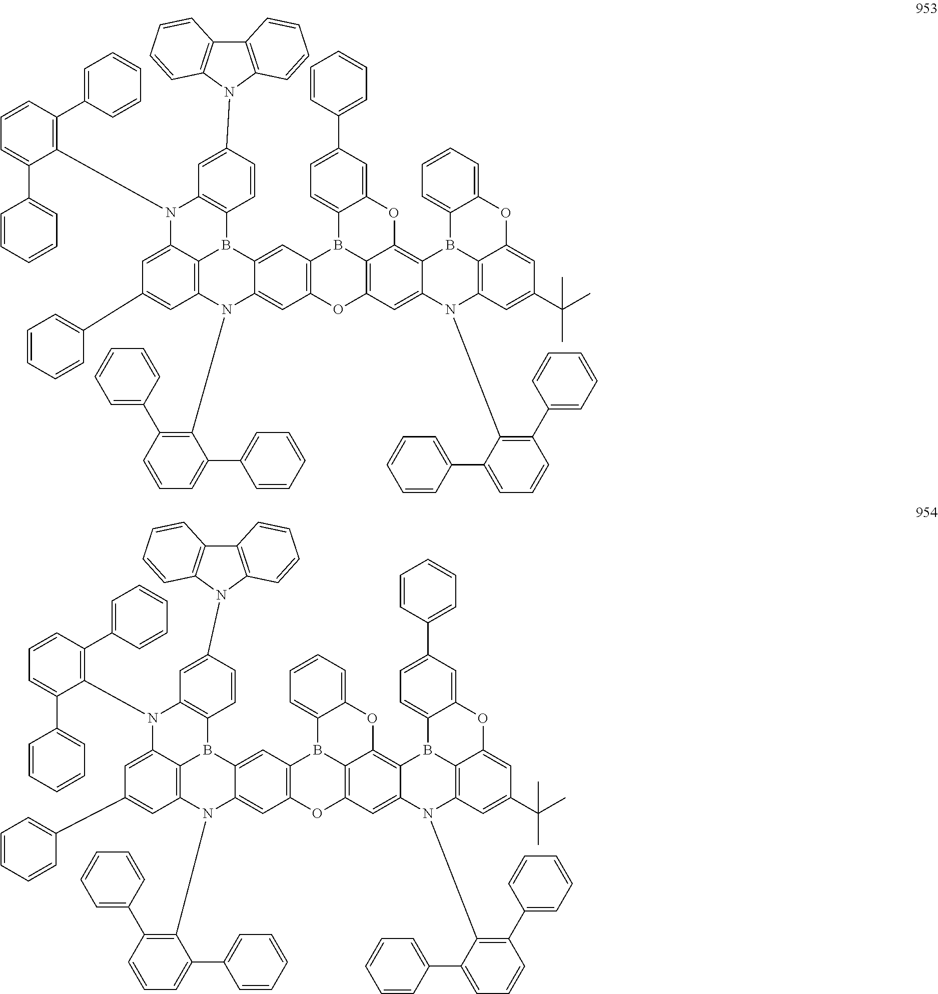 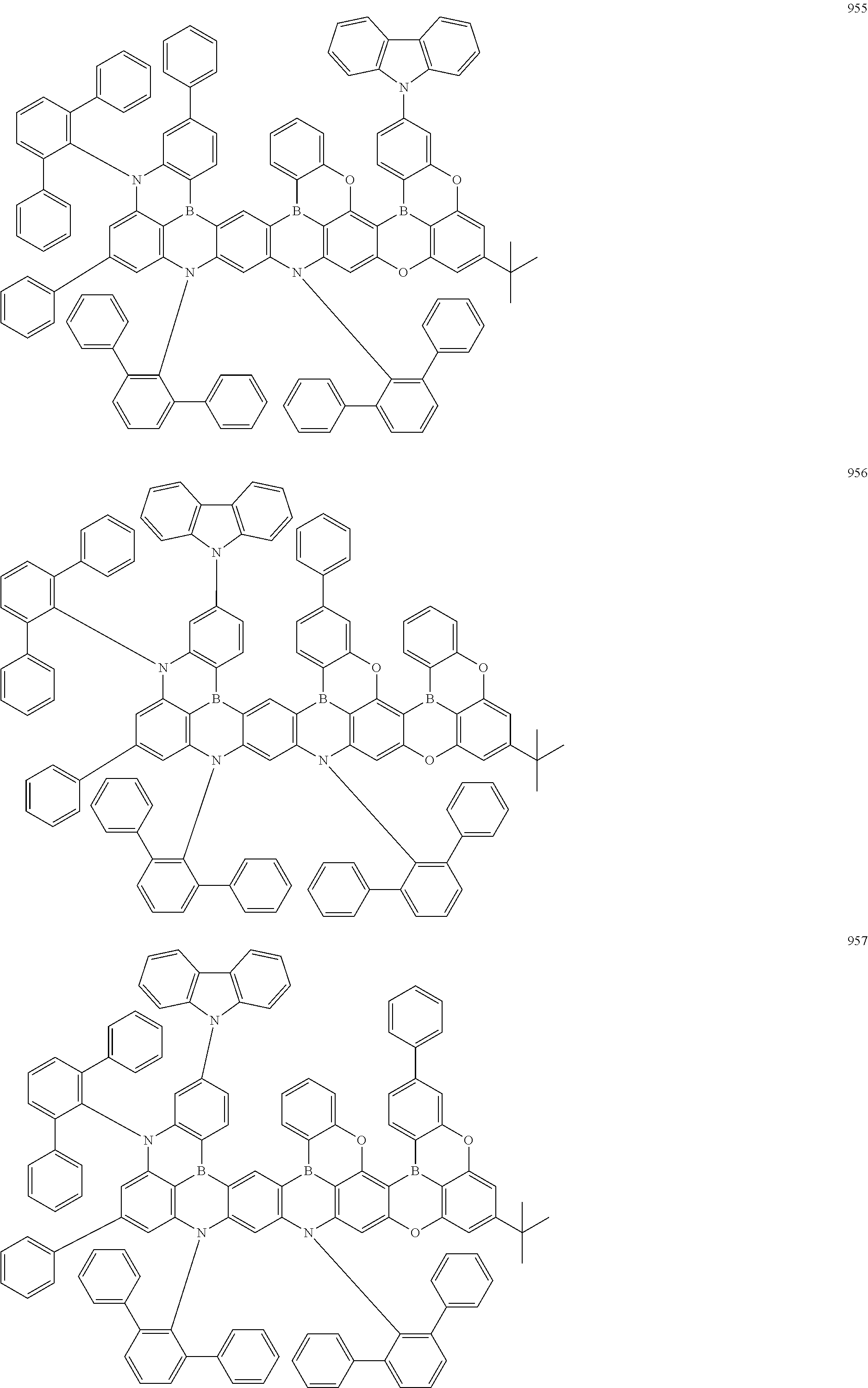 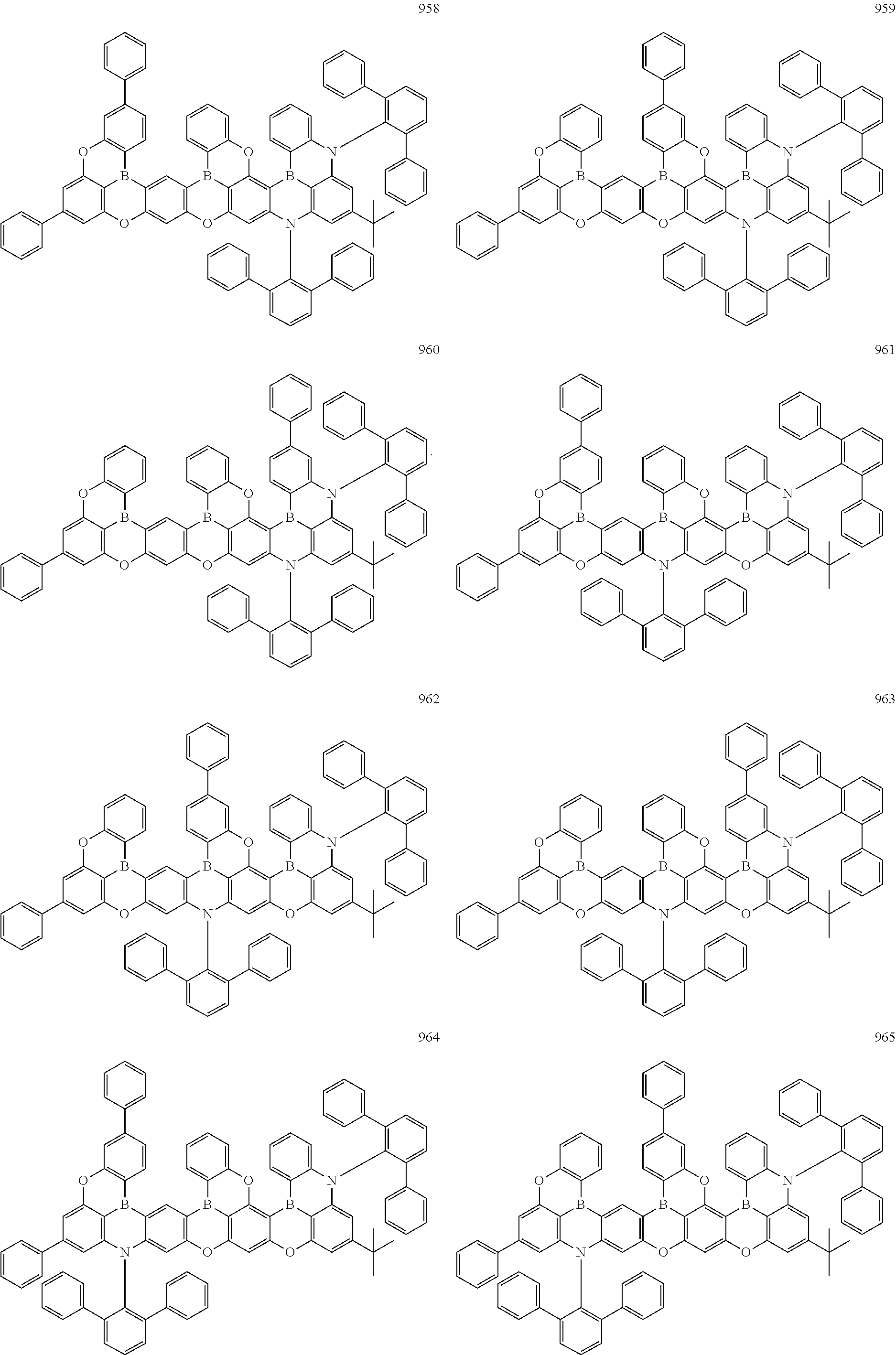 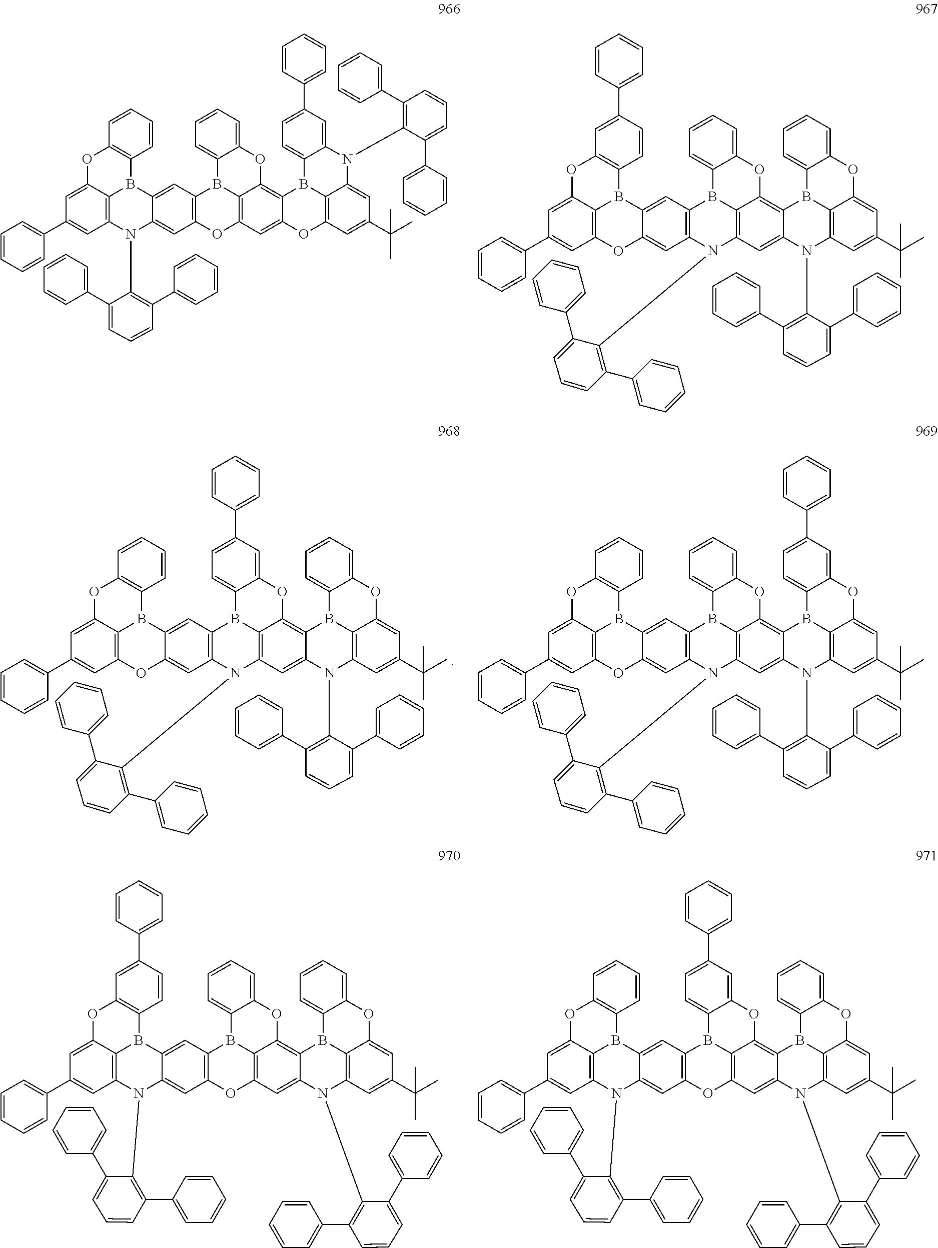 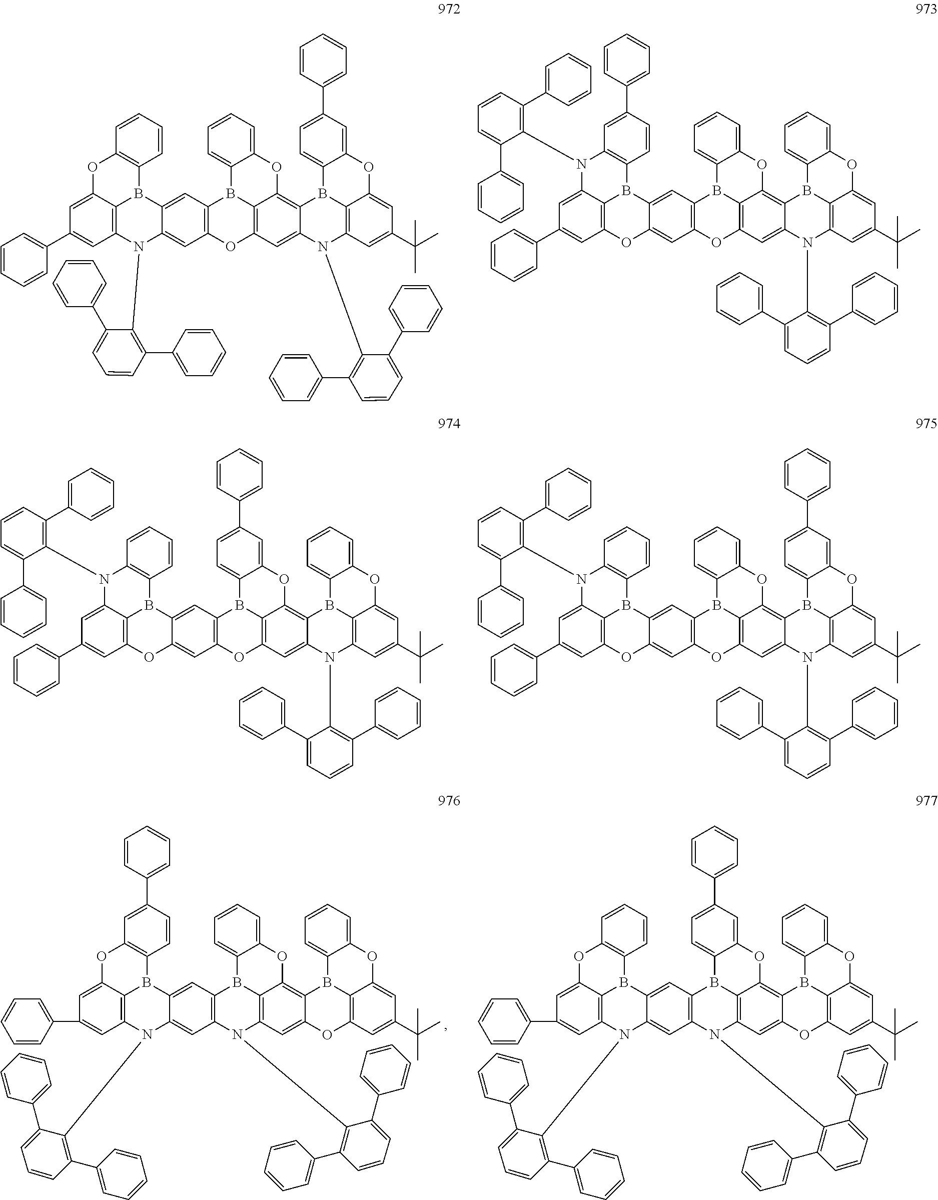 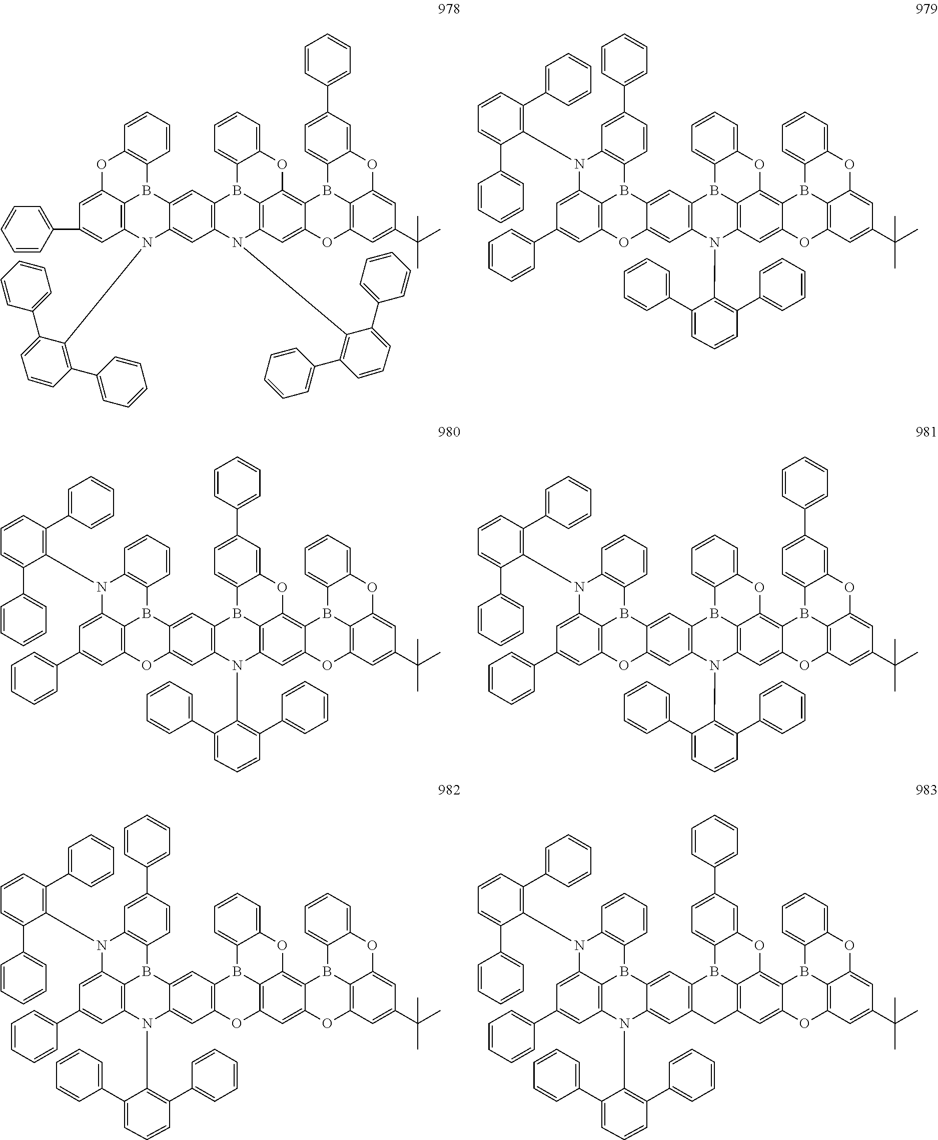 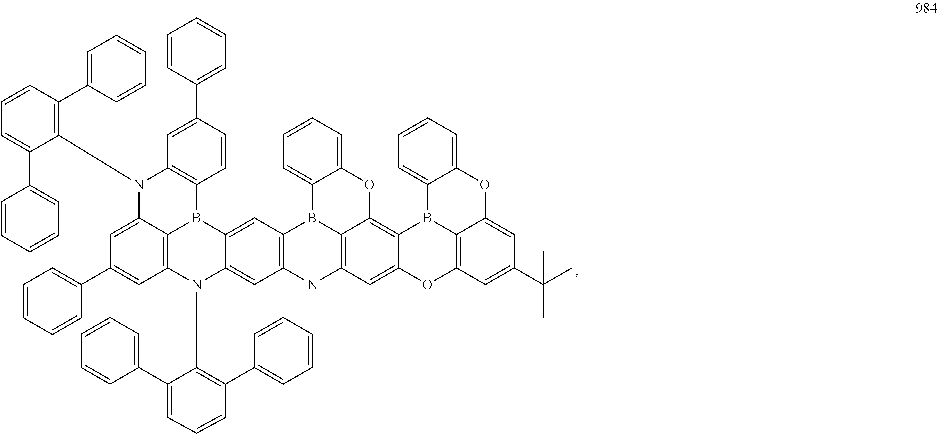 [SMILES: CC(C)(C)c1cc2c3c(c1)Oc1cc4c5c(c1B3c1ccccc1O2)Oc1ccccc1B5c1cc2c(cc1N4)N(c1c(-c3ccccc3)cccc1-c1ccccc1)c1cc(-c3ccccc3)cc3c1B2c1ccc(-c2ccccc2)cc1N3c1c(-c2ccccc2)cccc1-c1ccccc1] 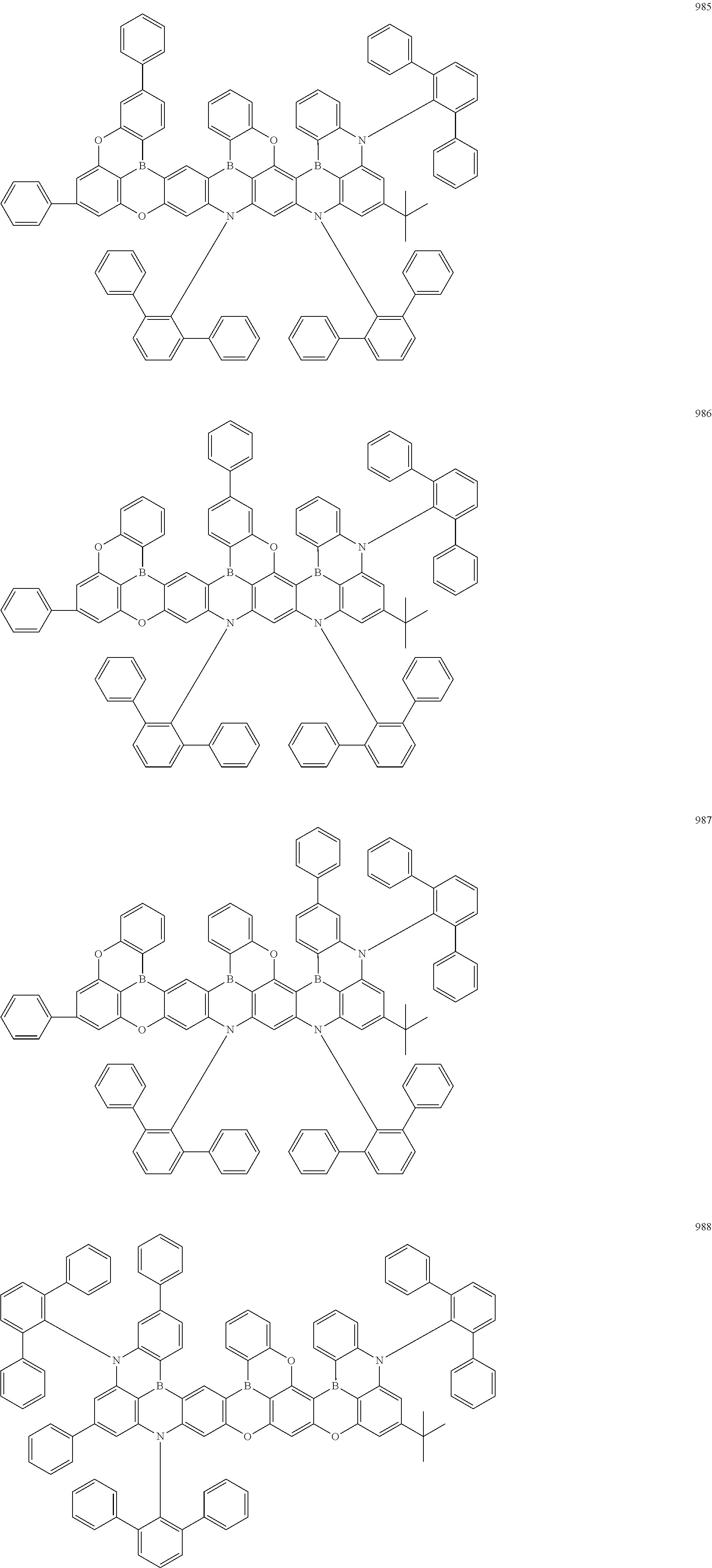 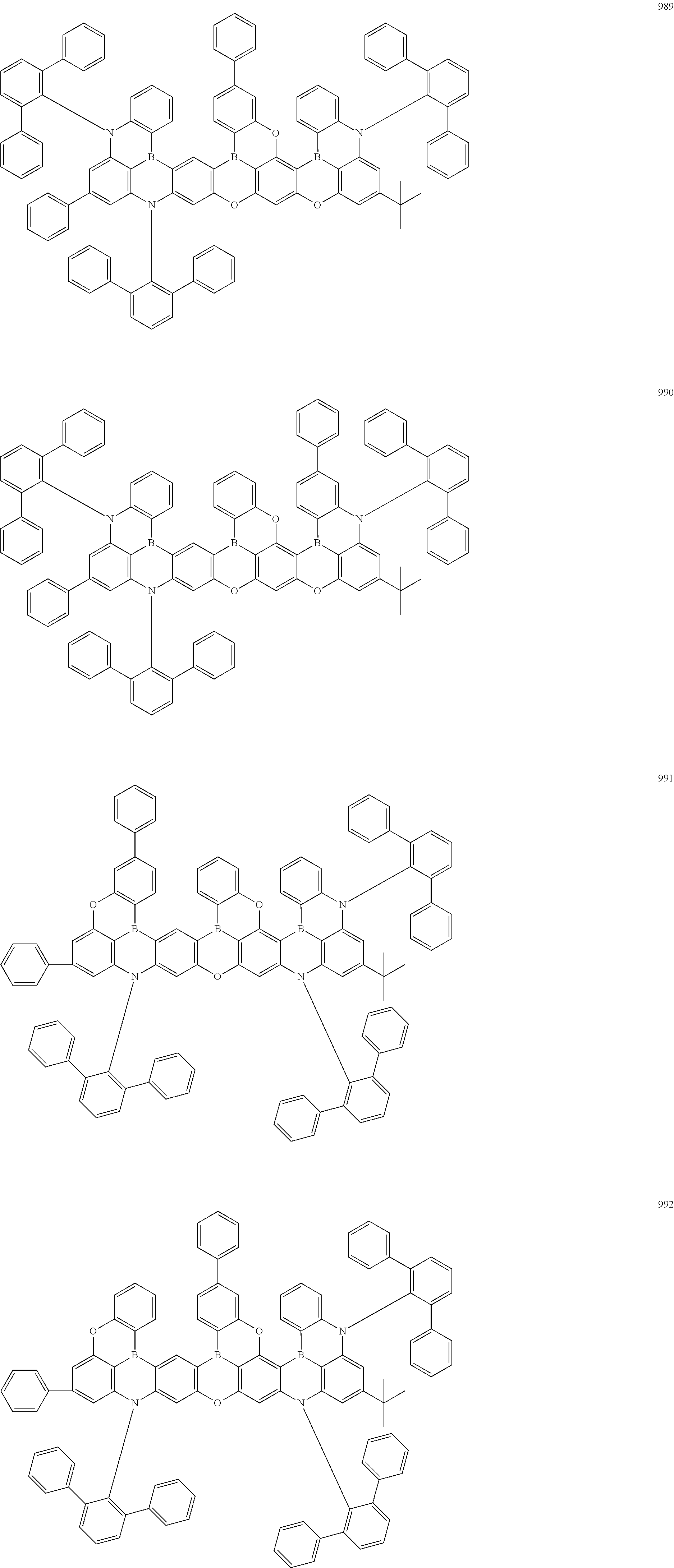 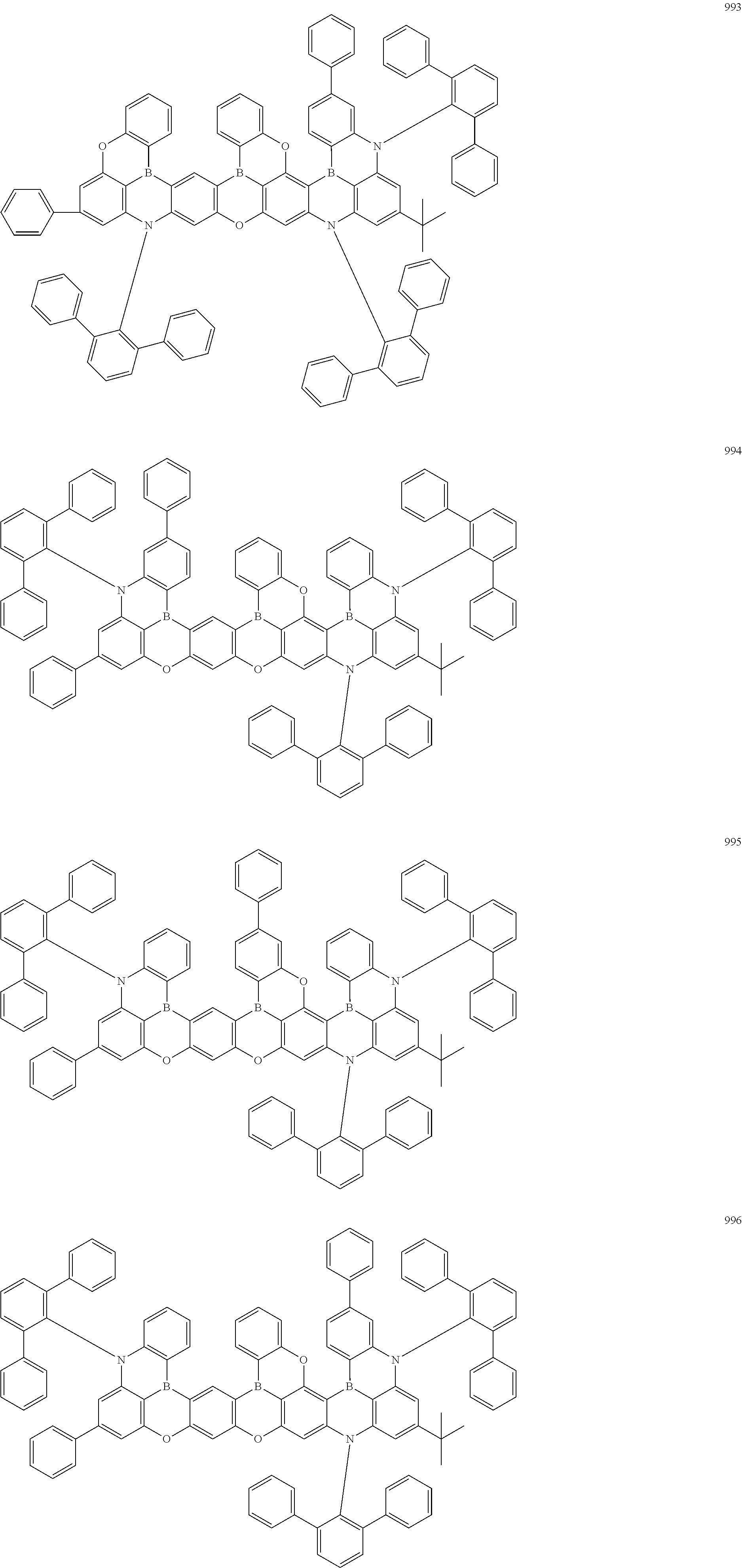 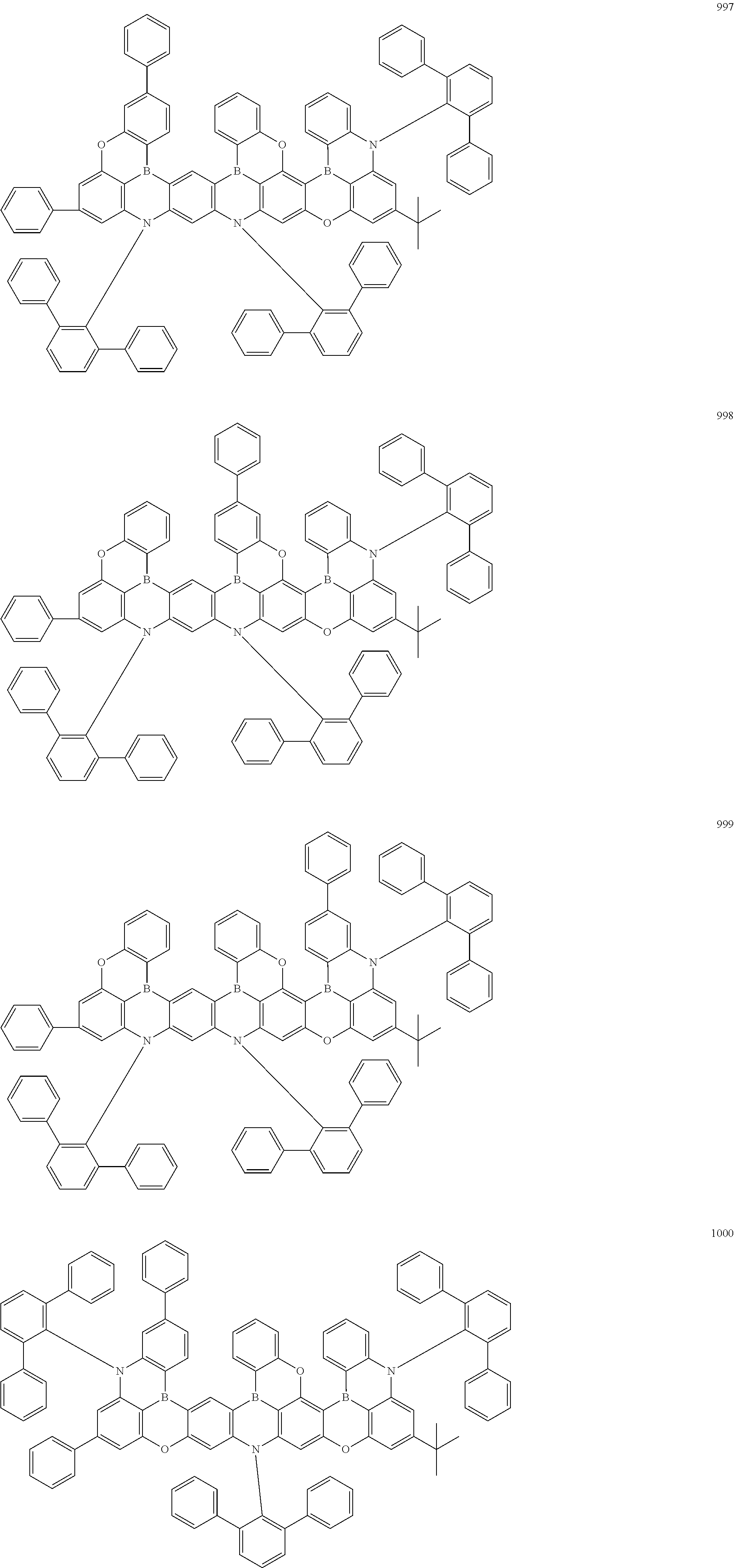 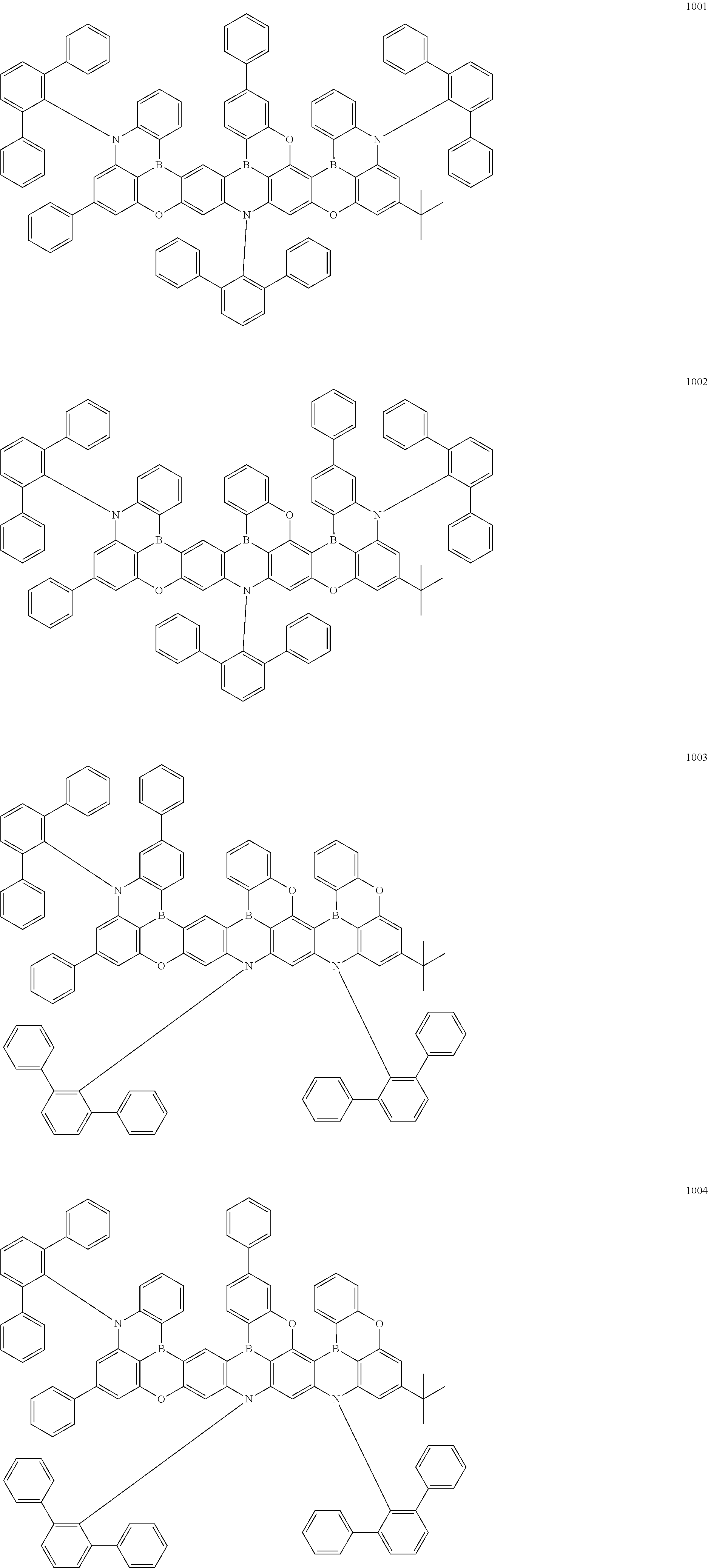 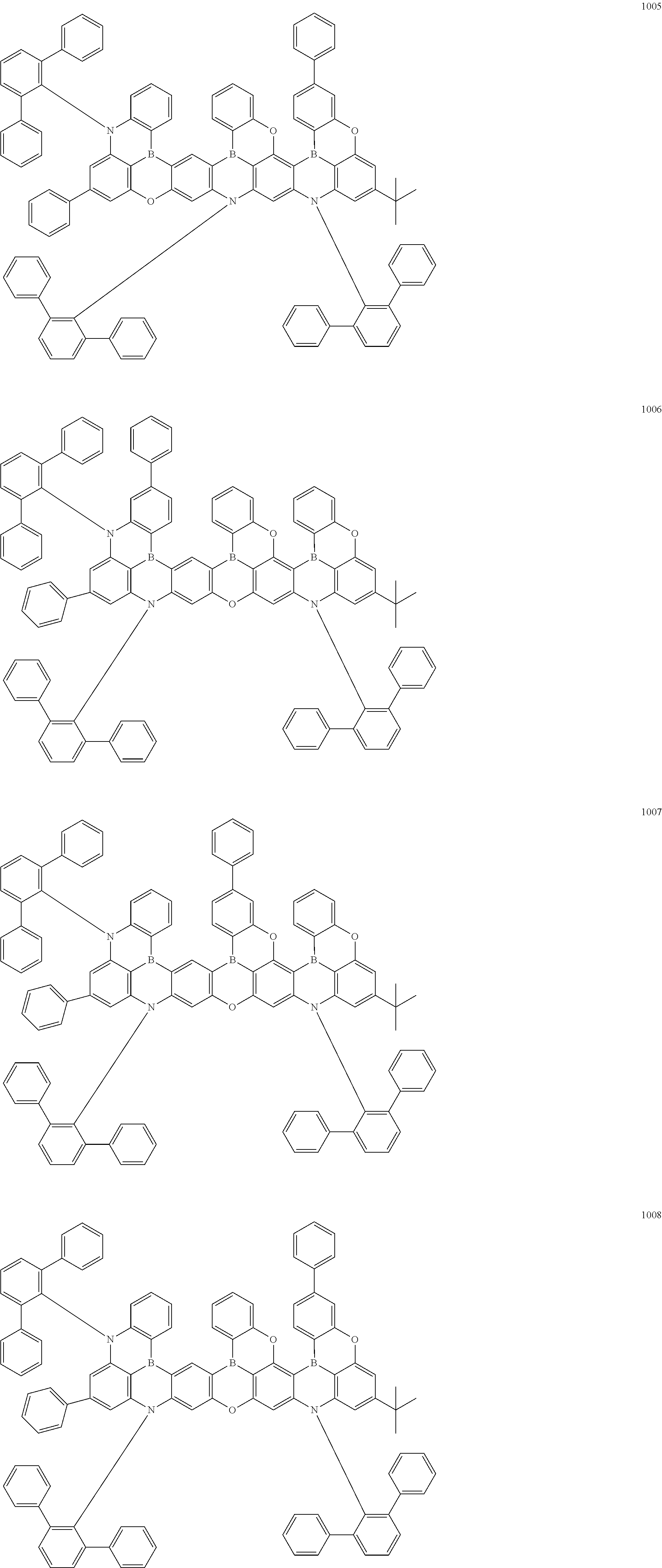 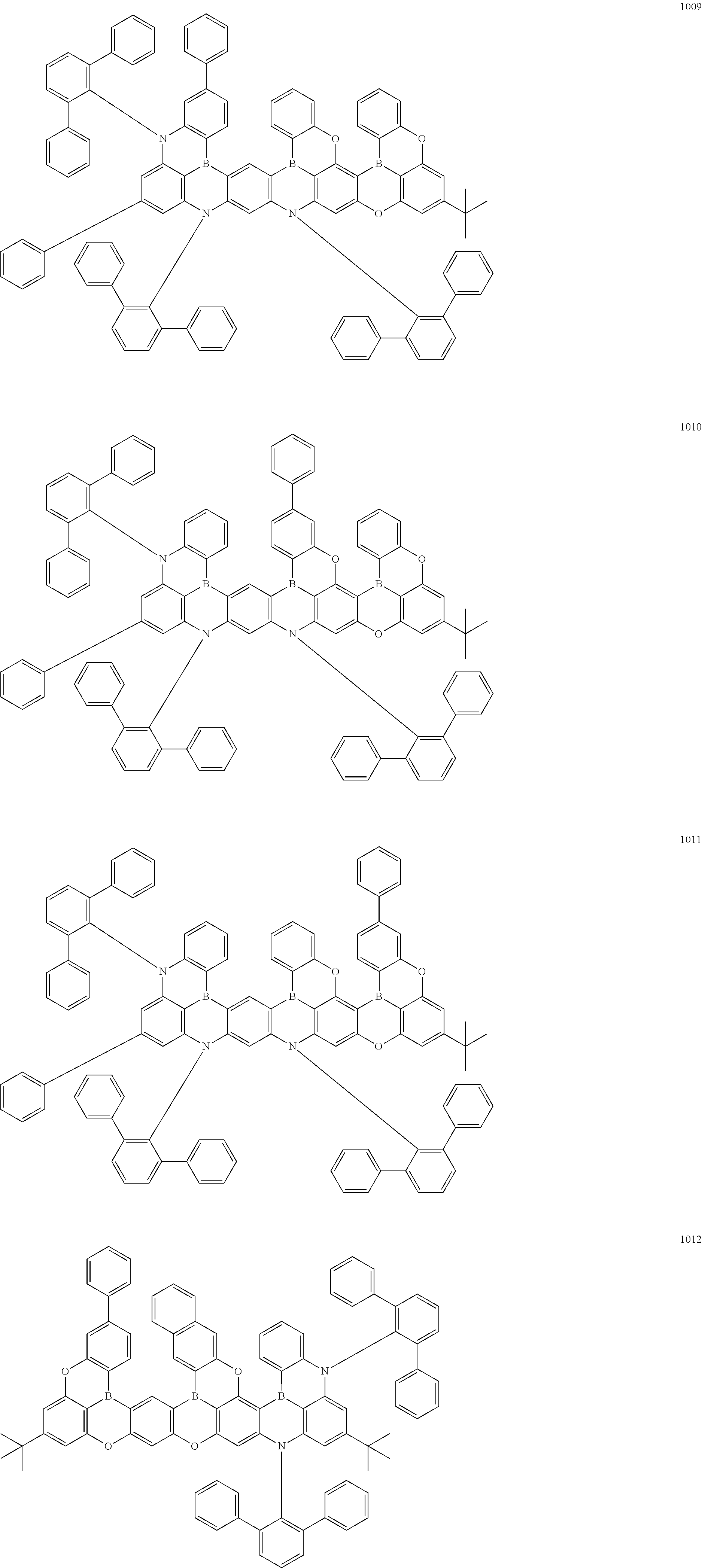 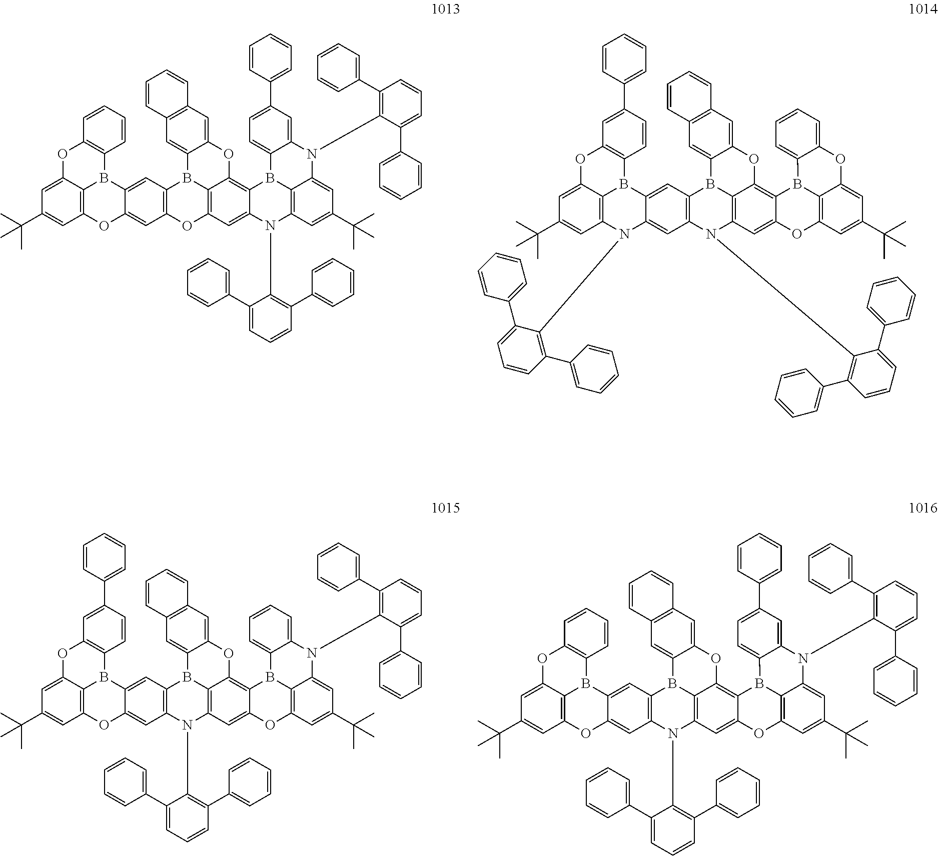 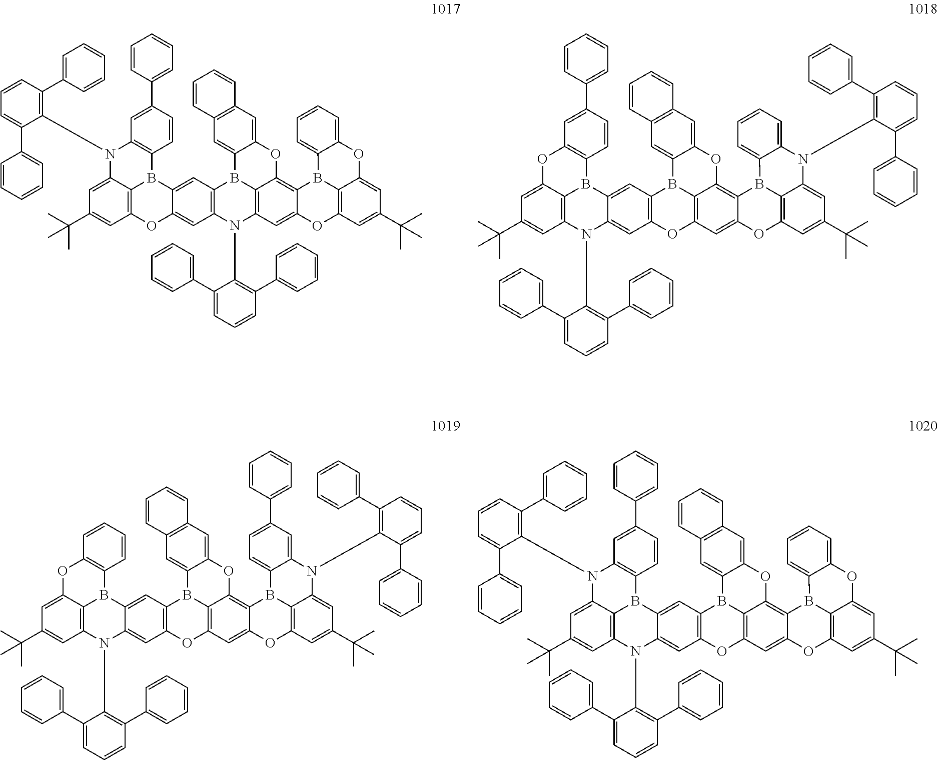 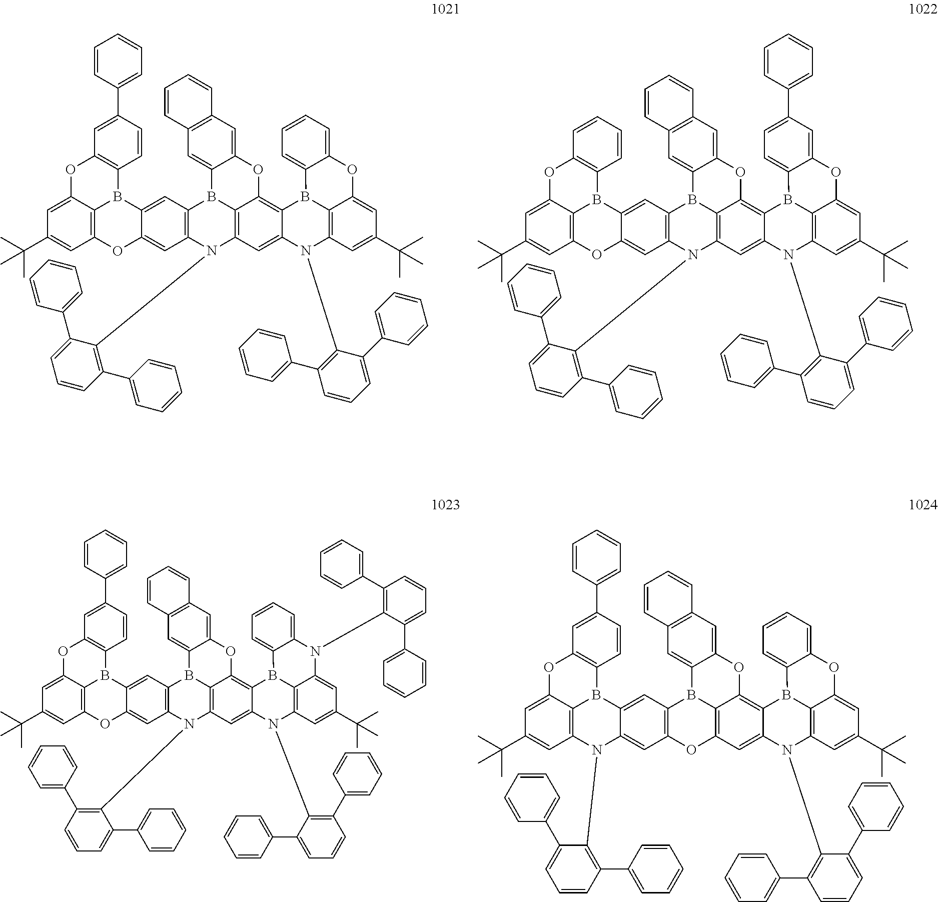 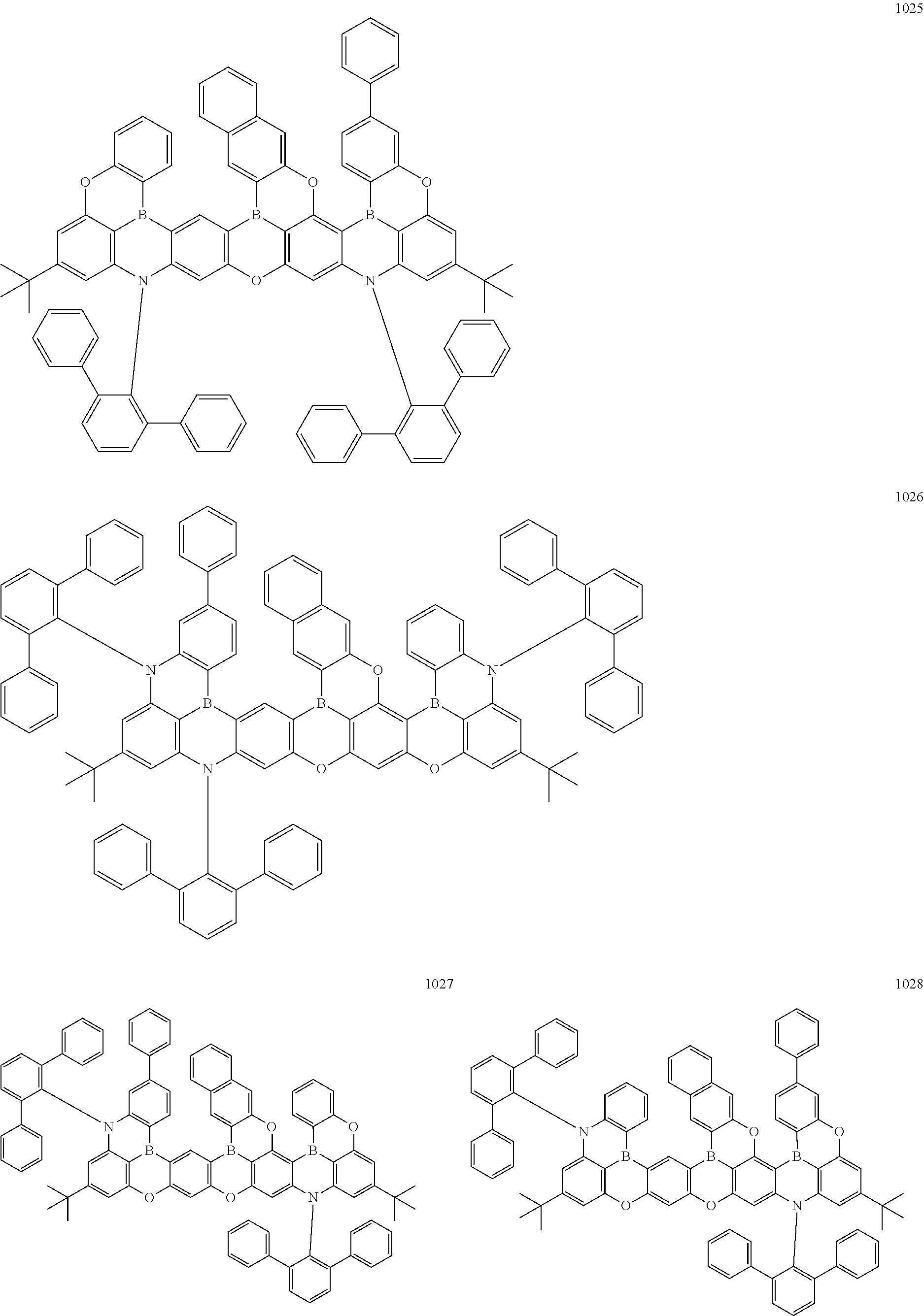 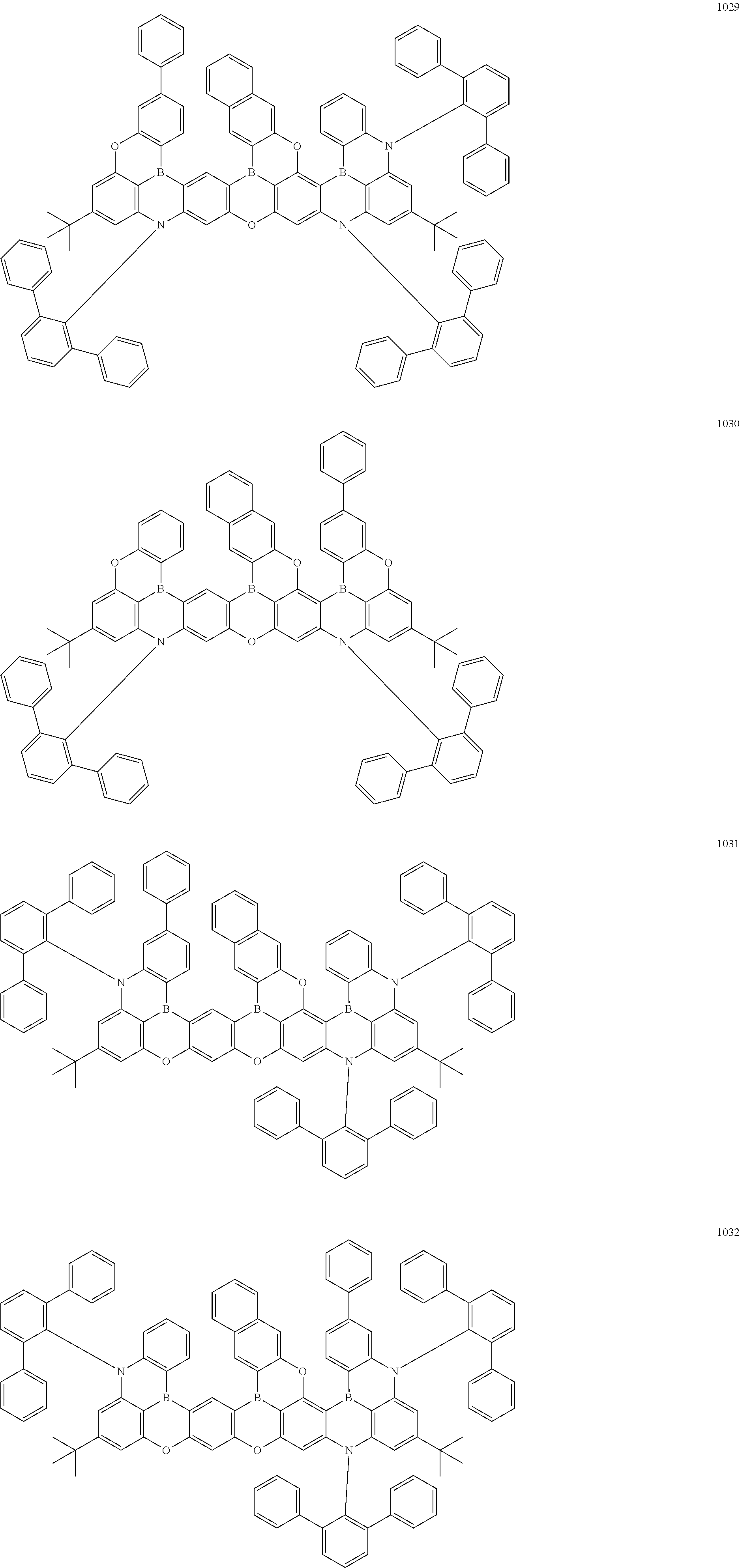 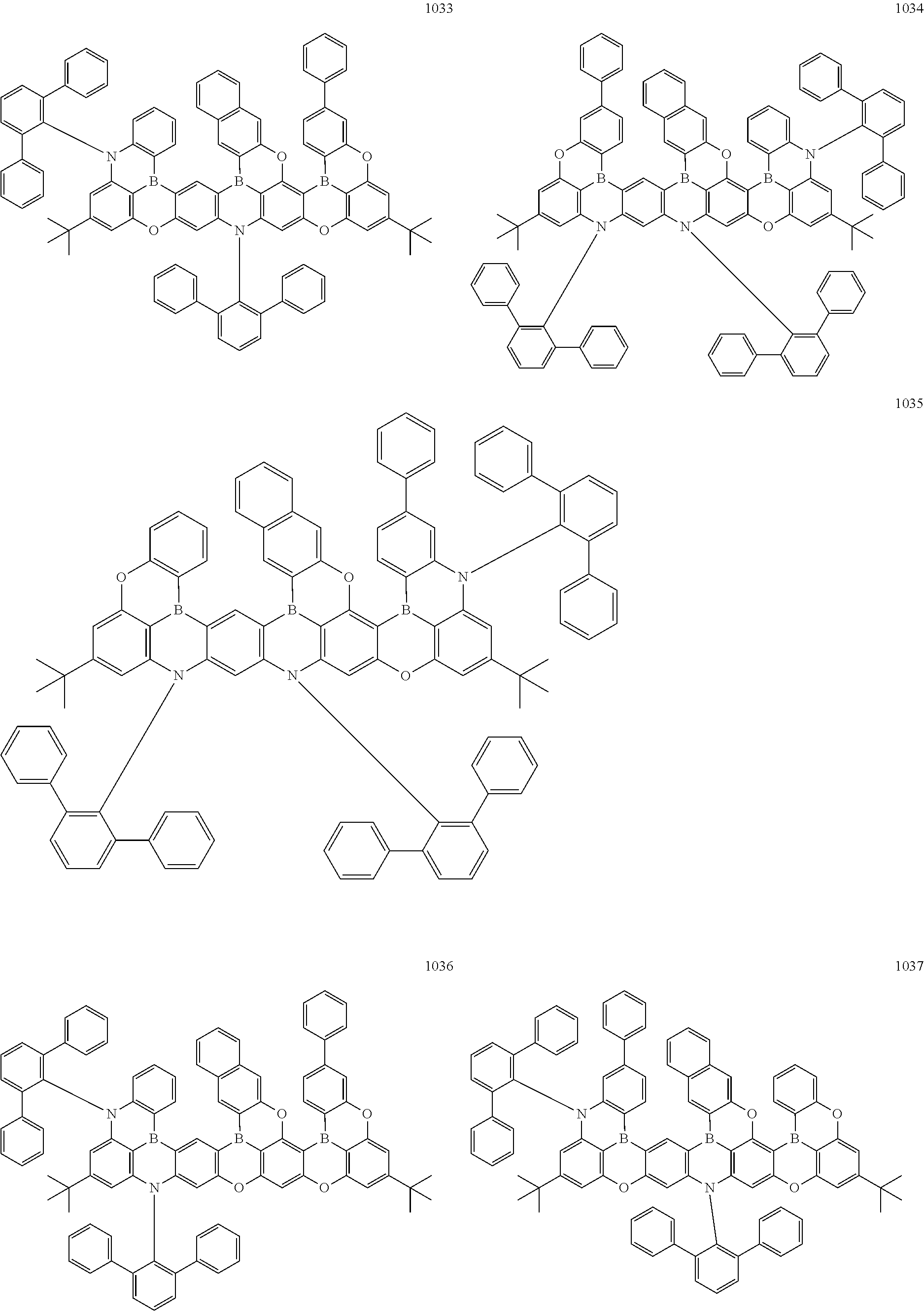 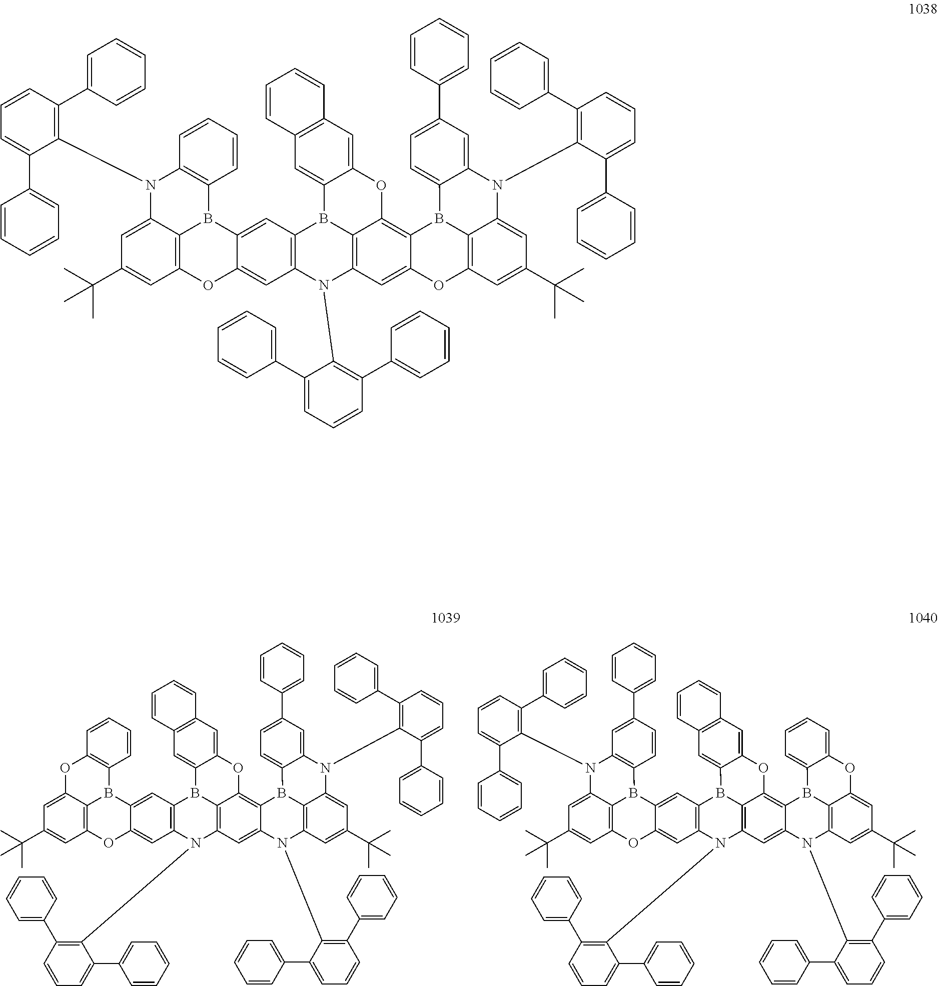 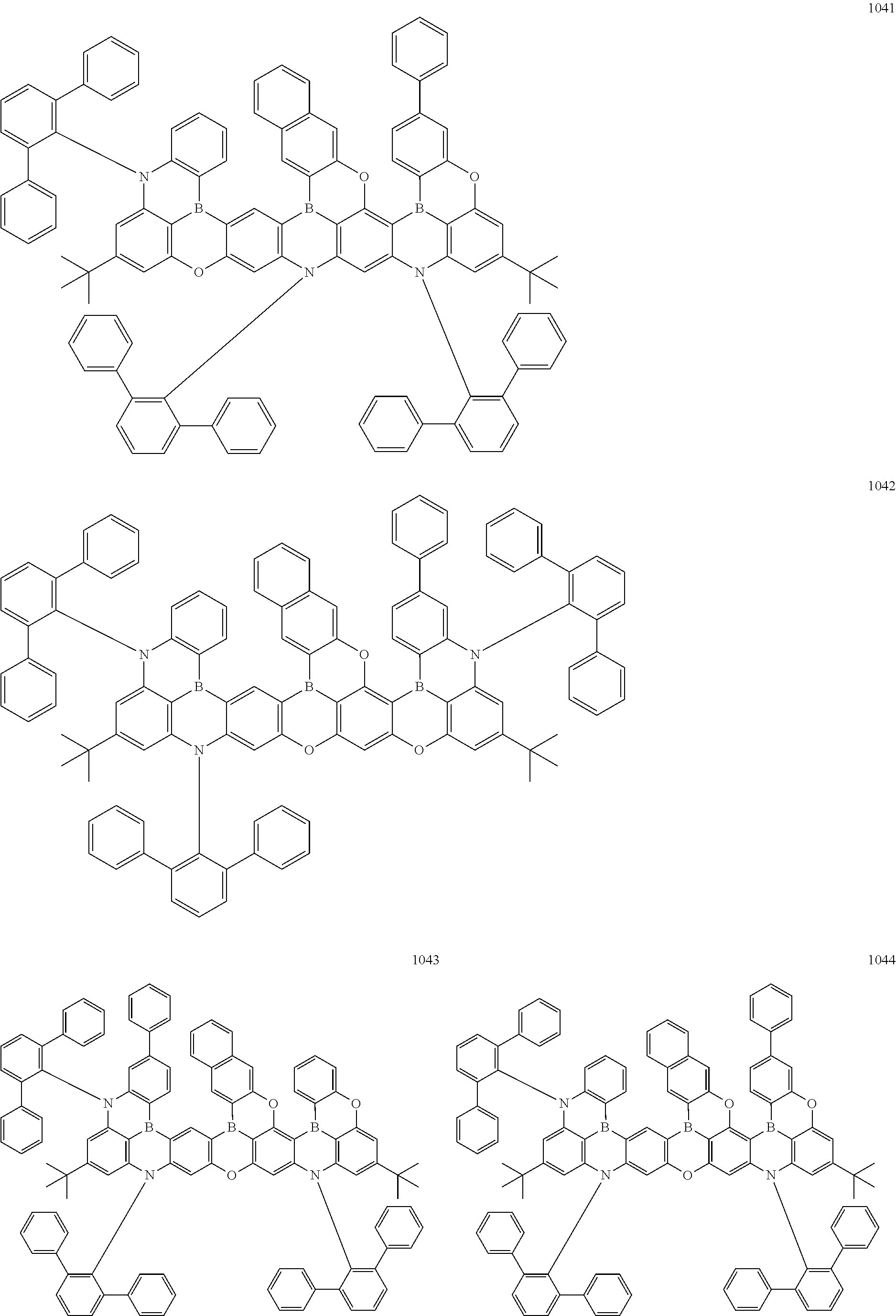 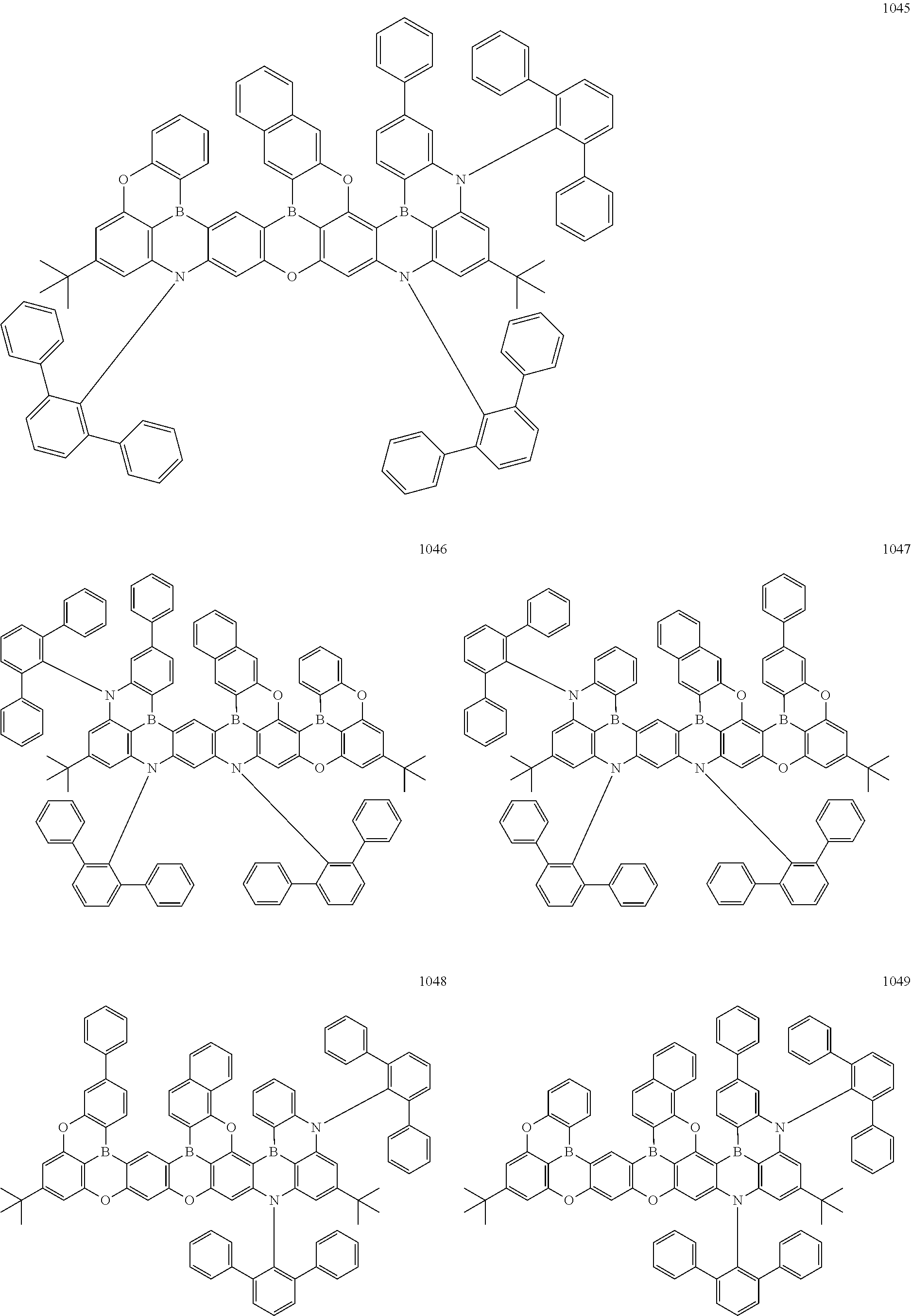 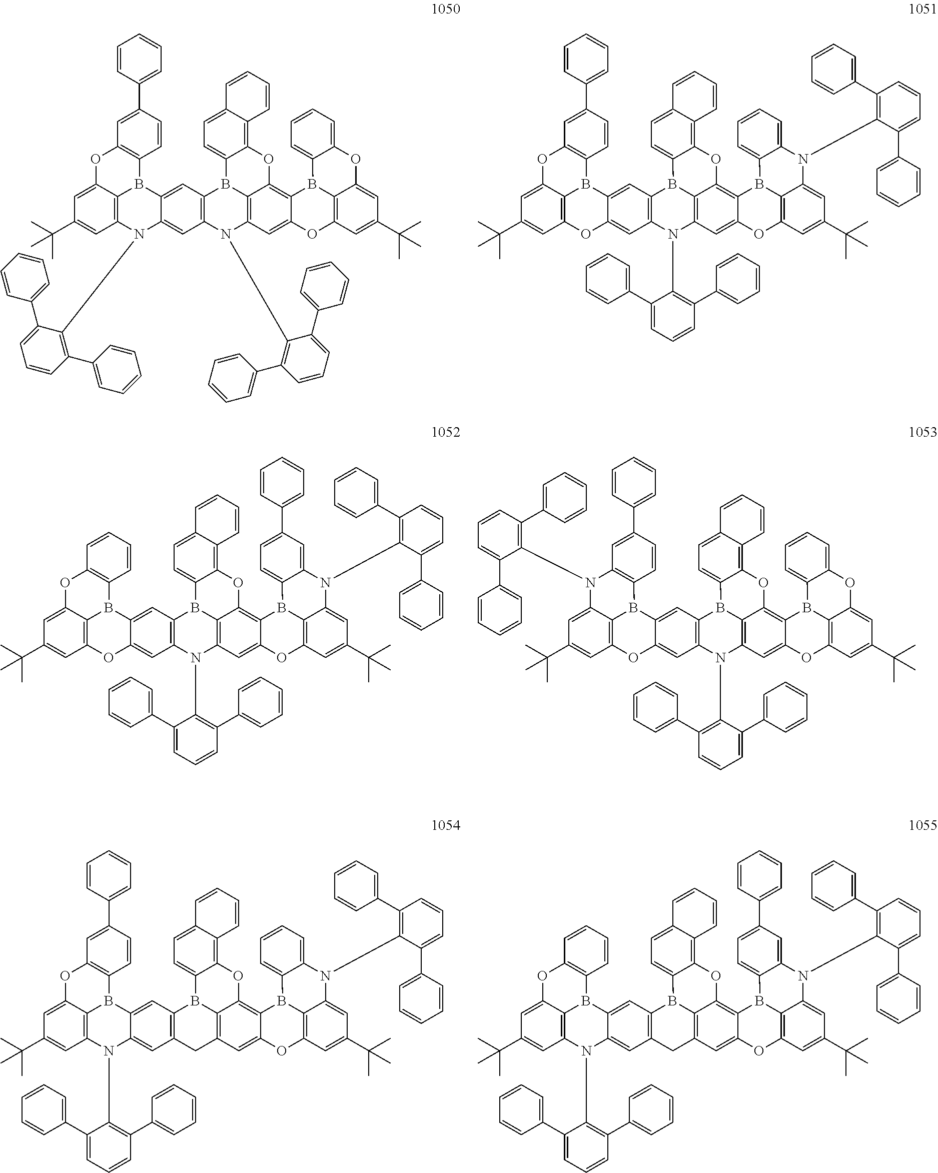 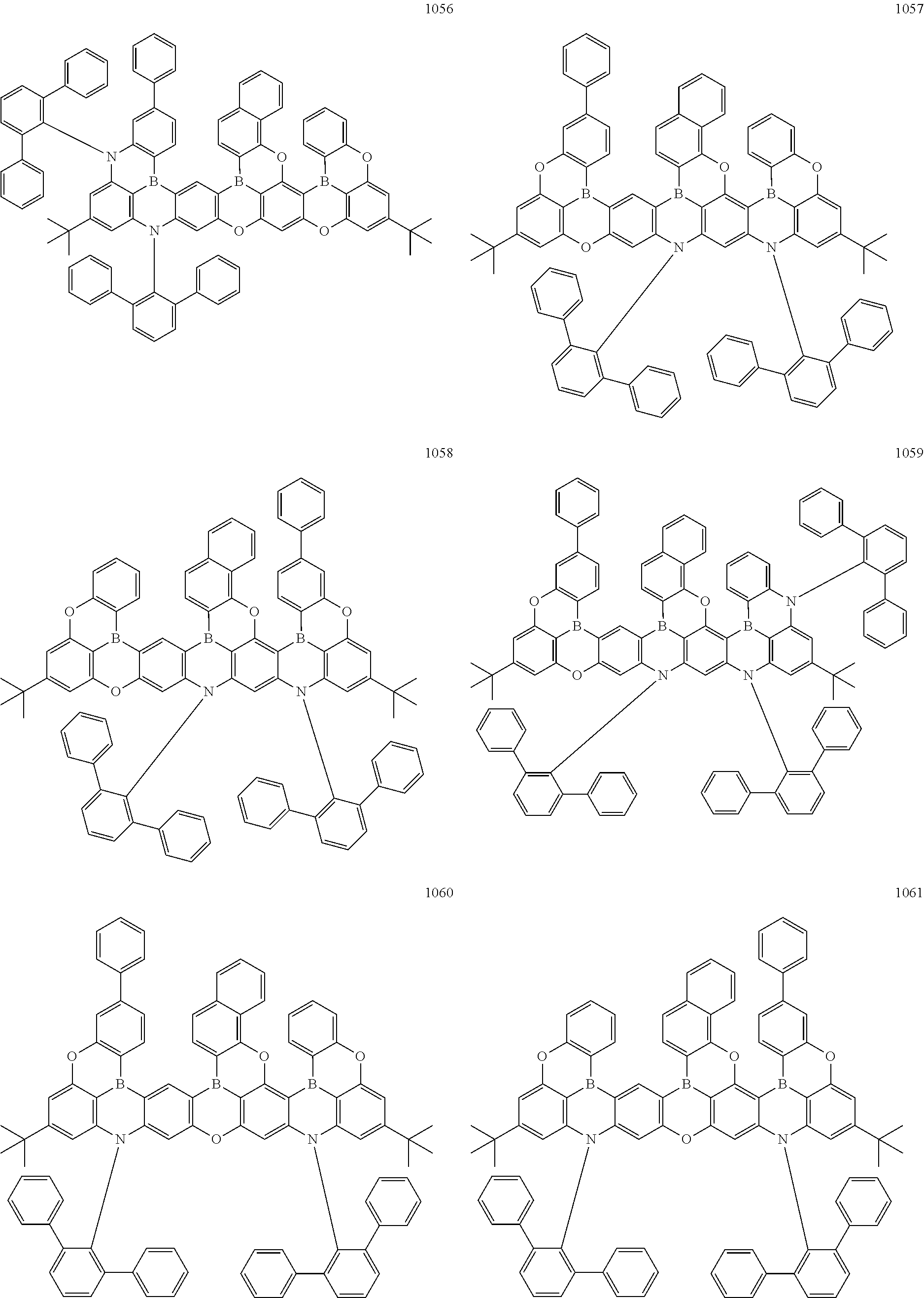 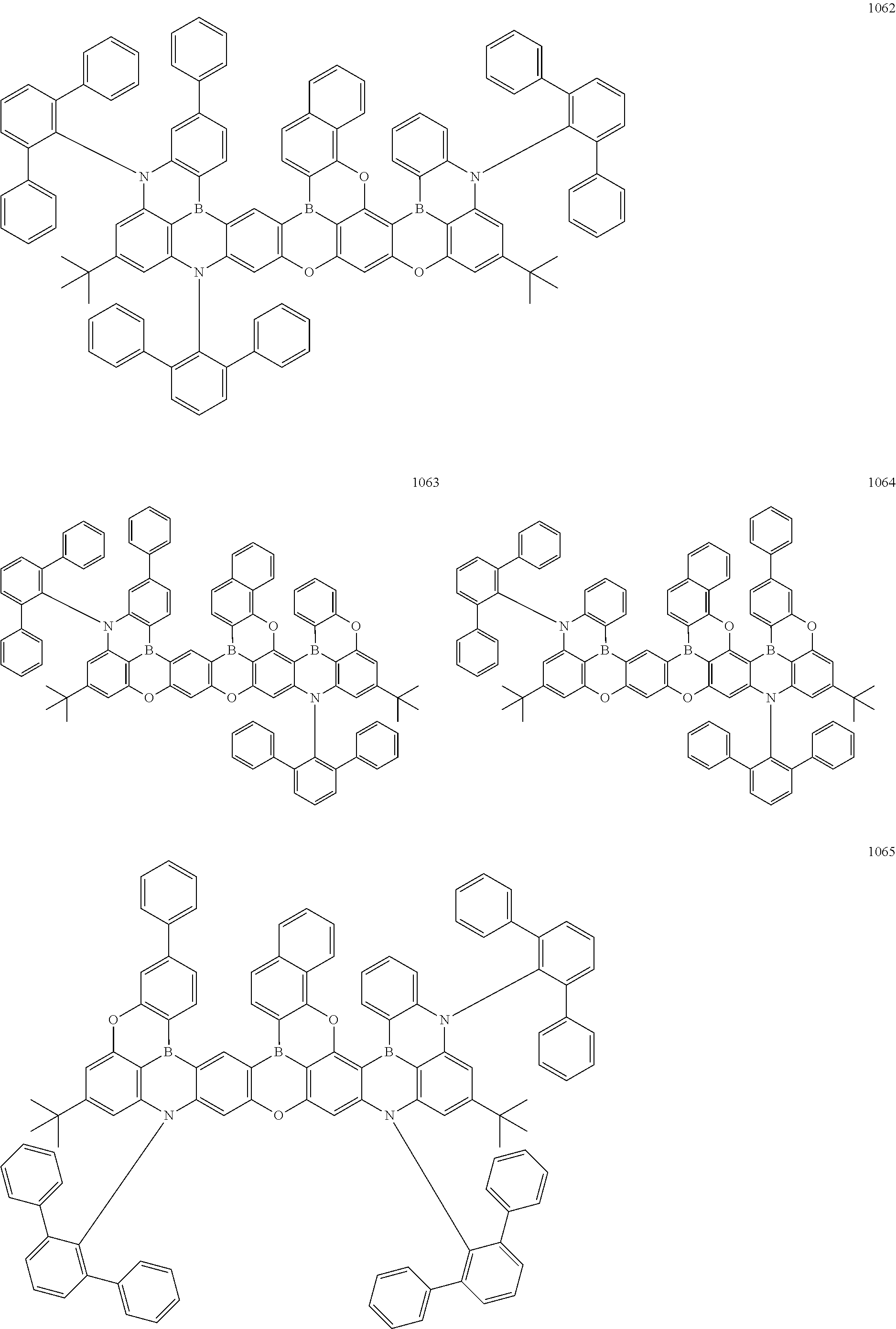 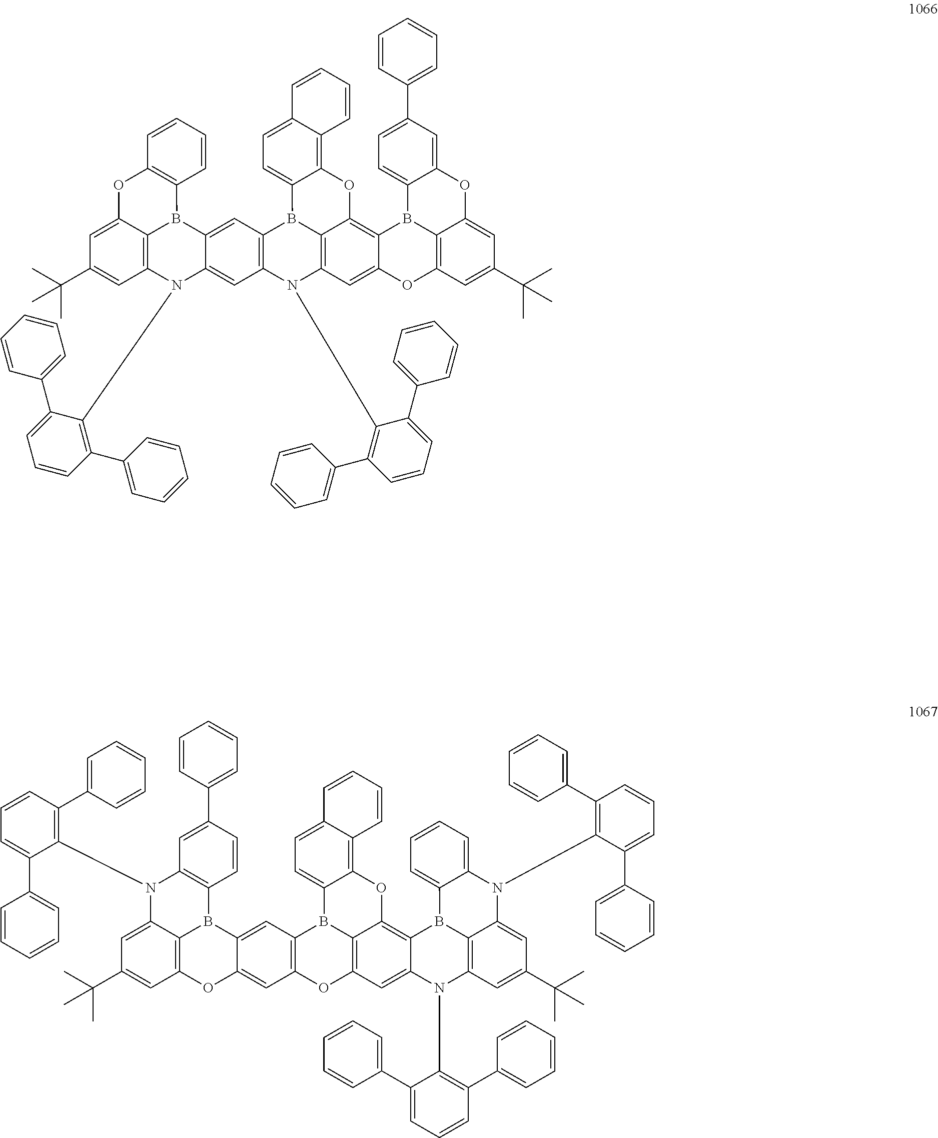 [SMILES: CC(C)(C)c1cc2c3c(c1)Oc1cc4c5c(c1B3c1ccc(-c3ccccc3)cc1O2)Oc1c(ccc2ccccc12)B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccccc1O3 ; CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccc3ccccc3c1O4)B1c3ccccc3N(c3c(-c4ccccc4)cccc3-c3ccccc3)c3cc(C(C)(C)C)cc(c31)N2c1c(-c2ccccc2)cccc1-c1ccccc1] 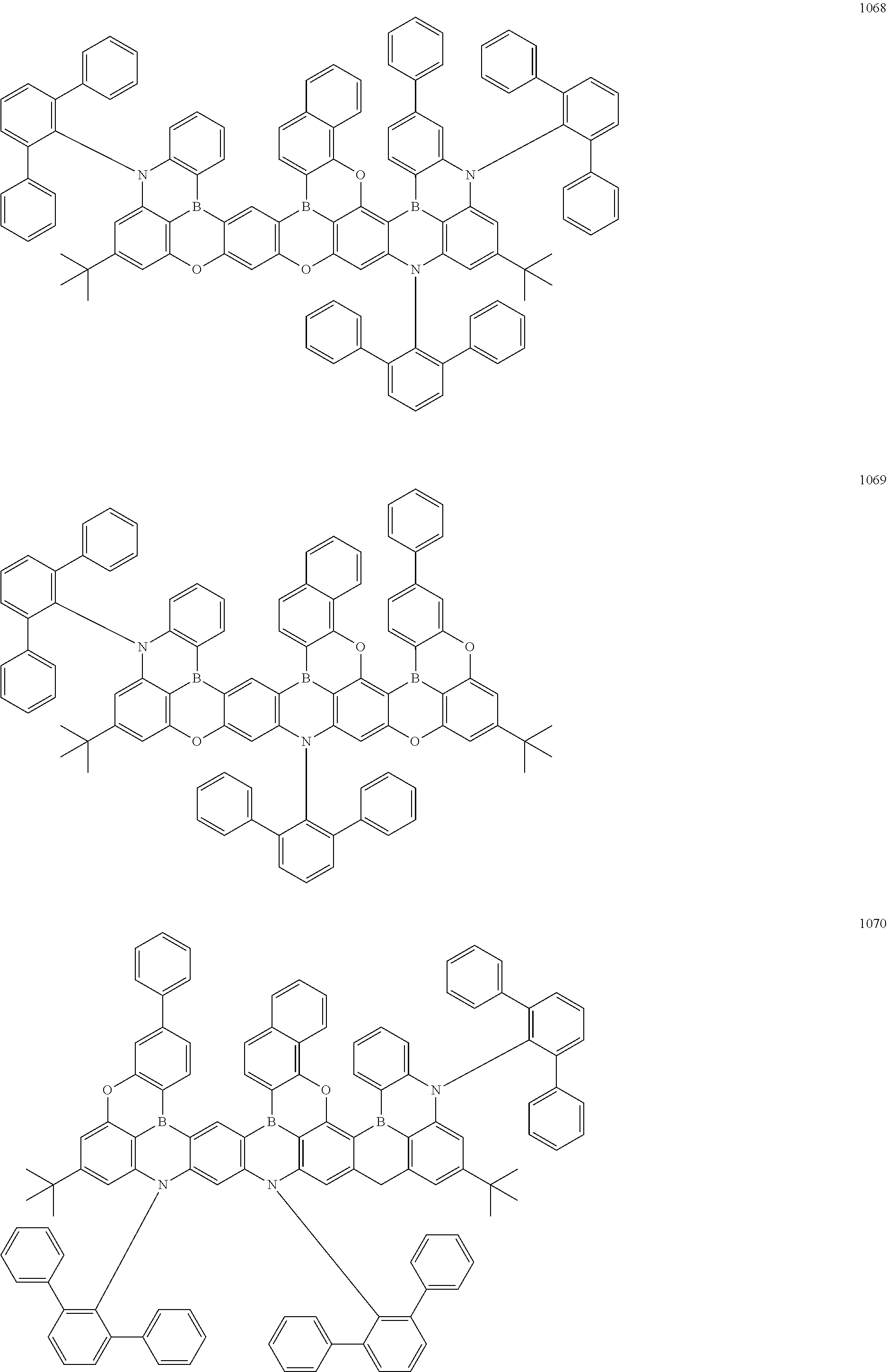 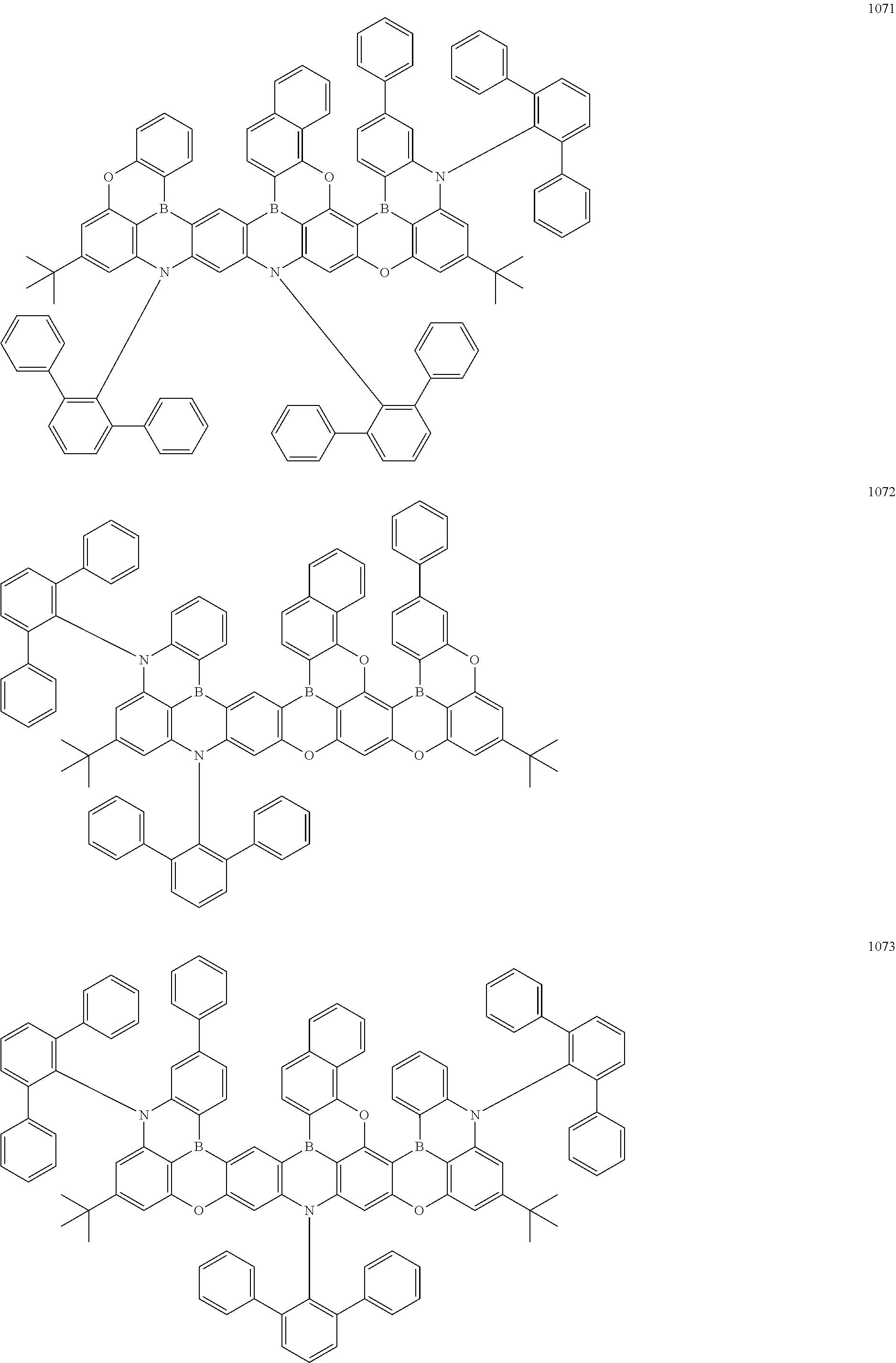 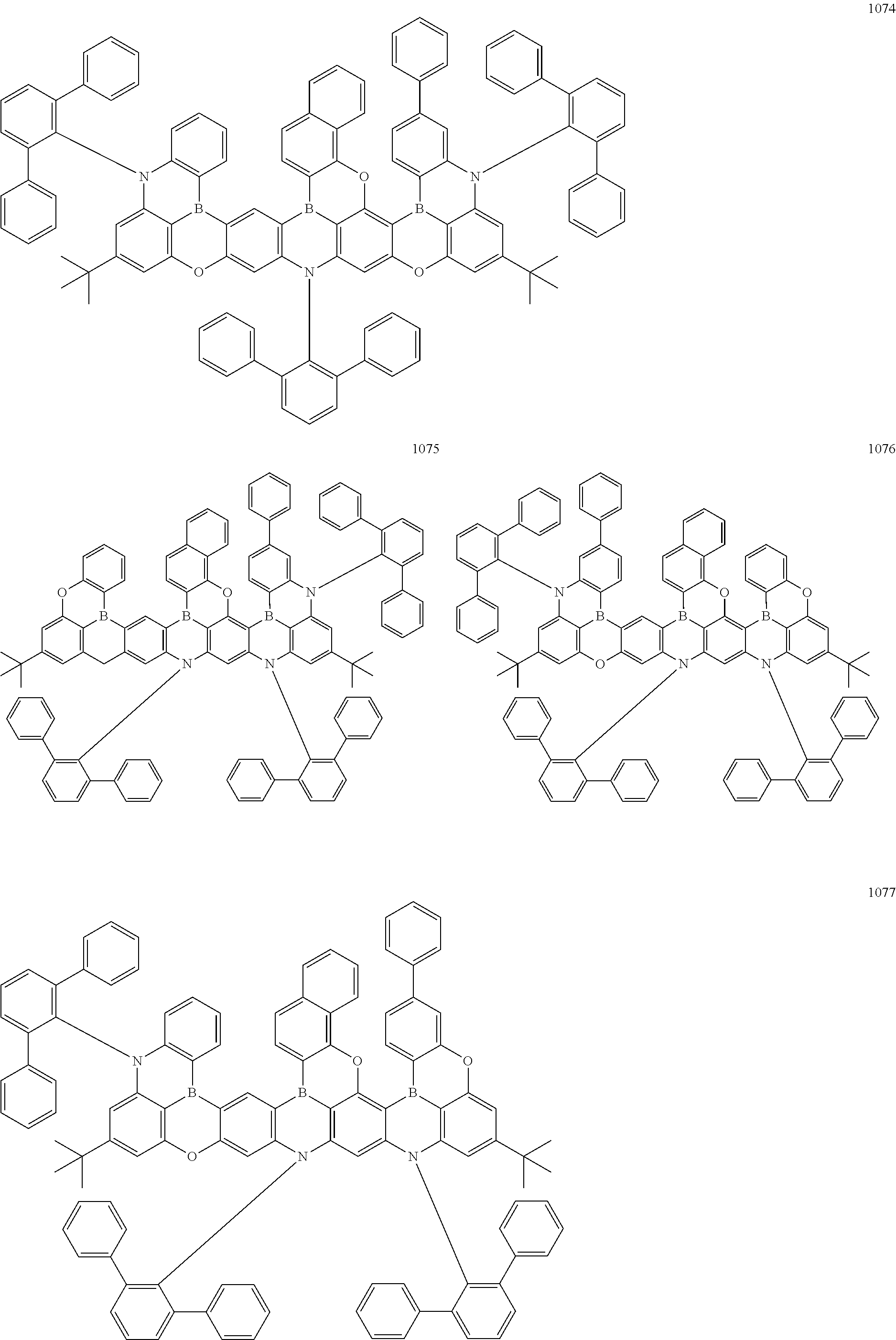 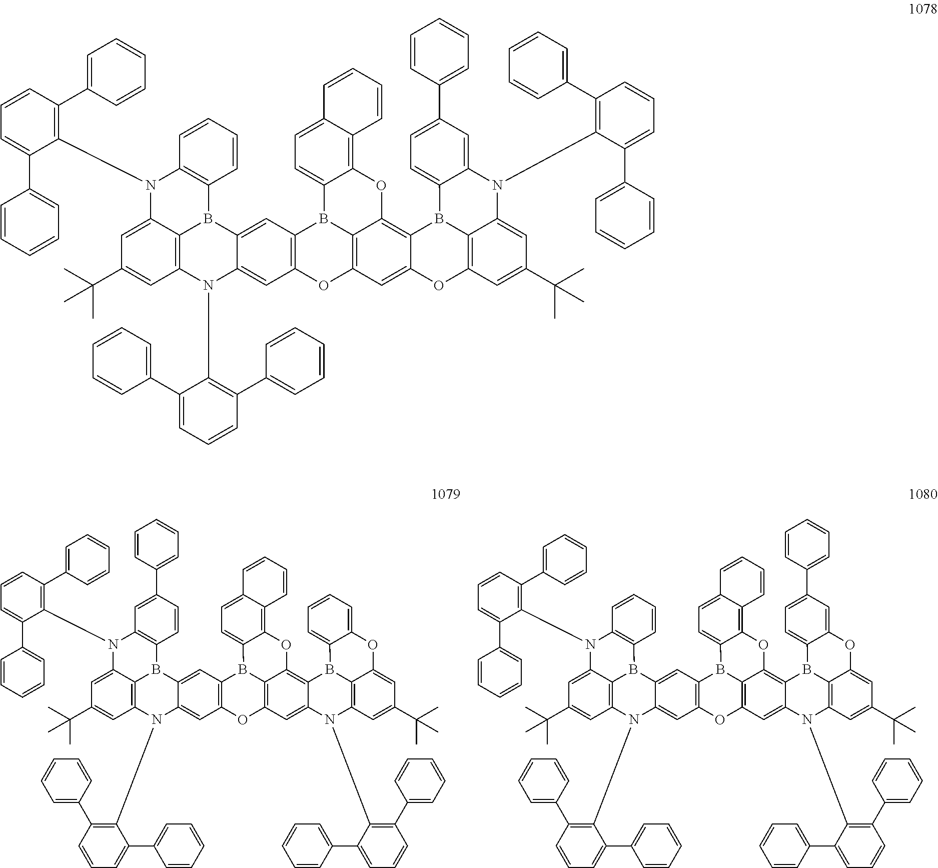 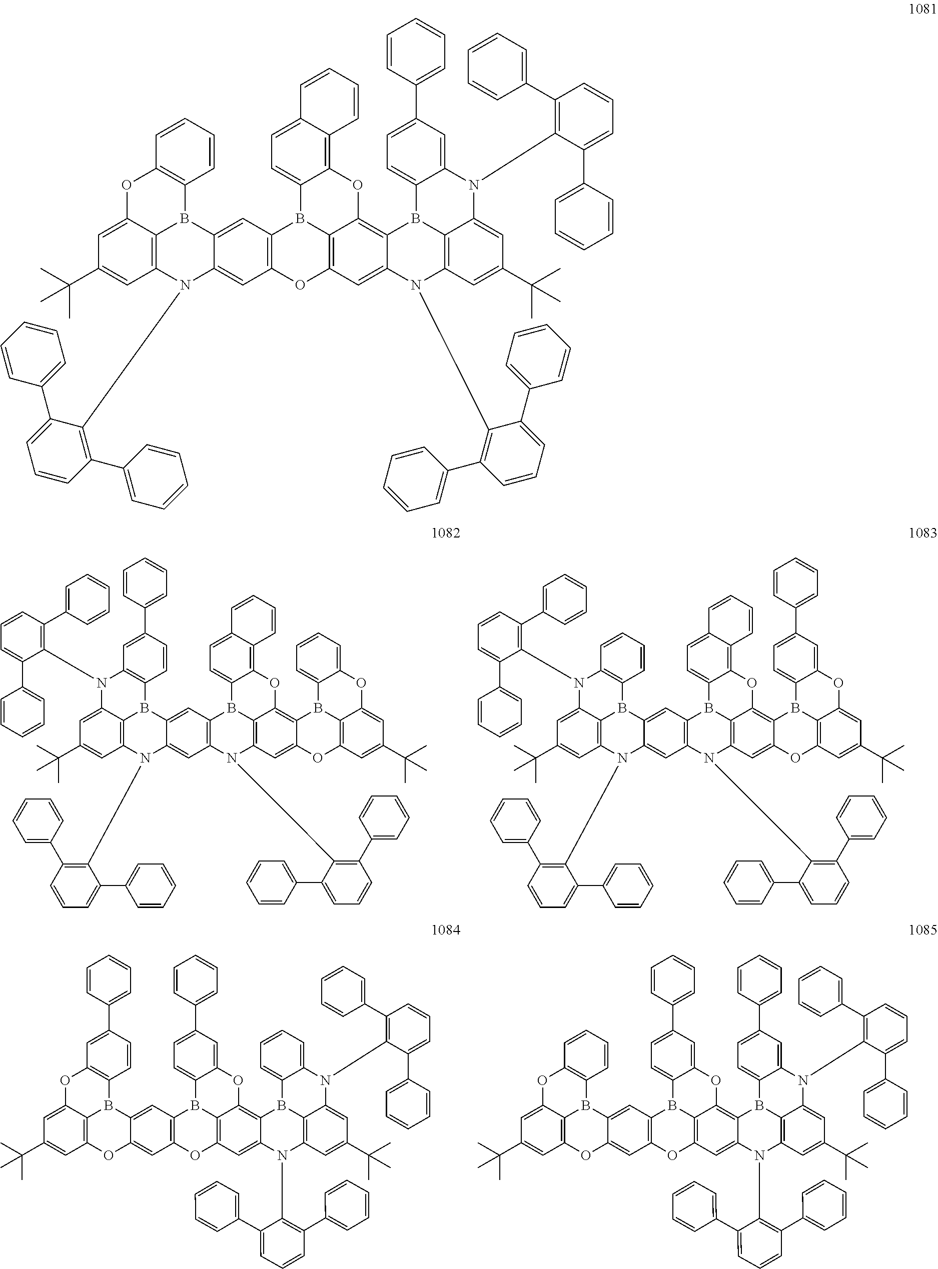 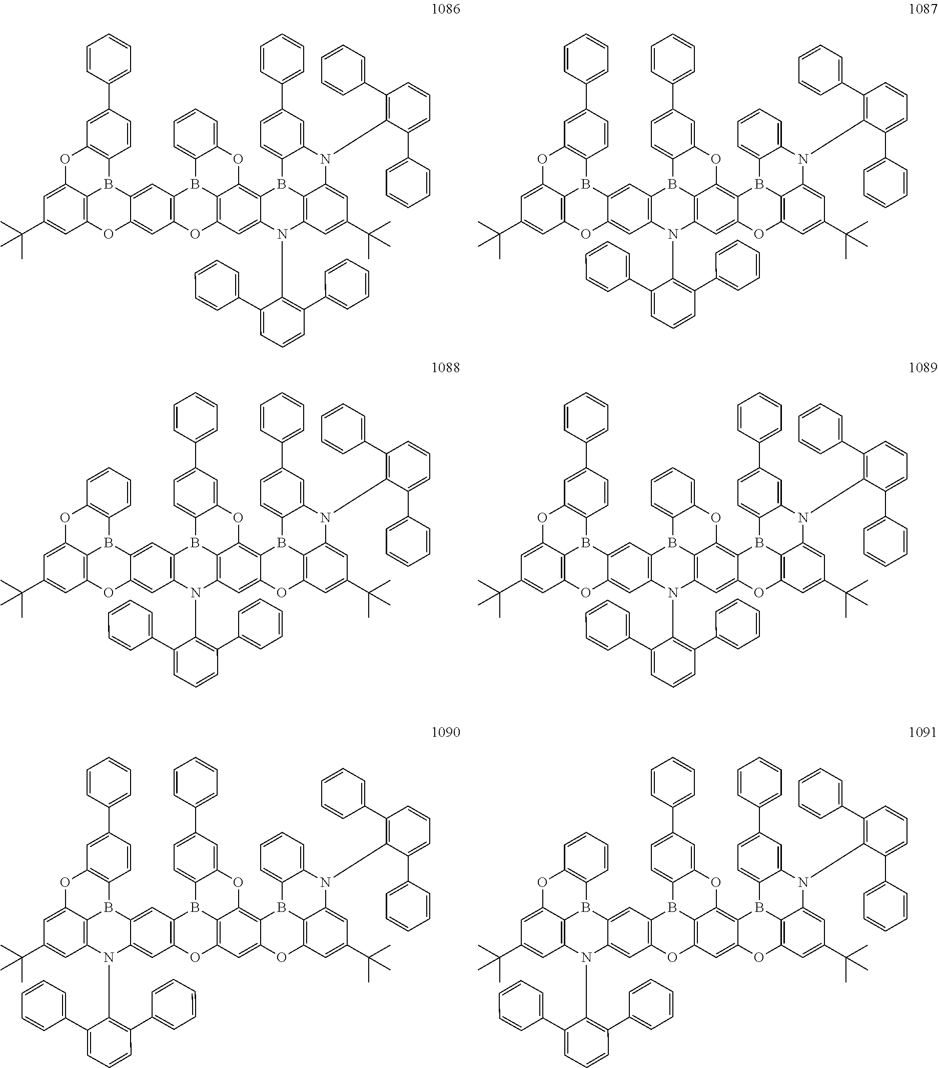 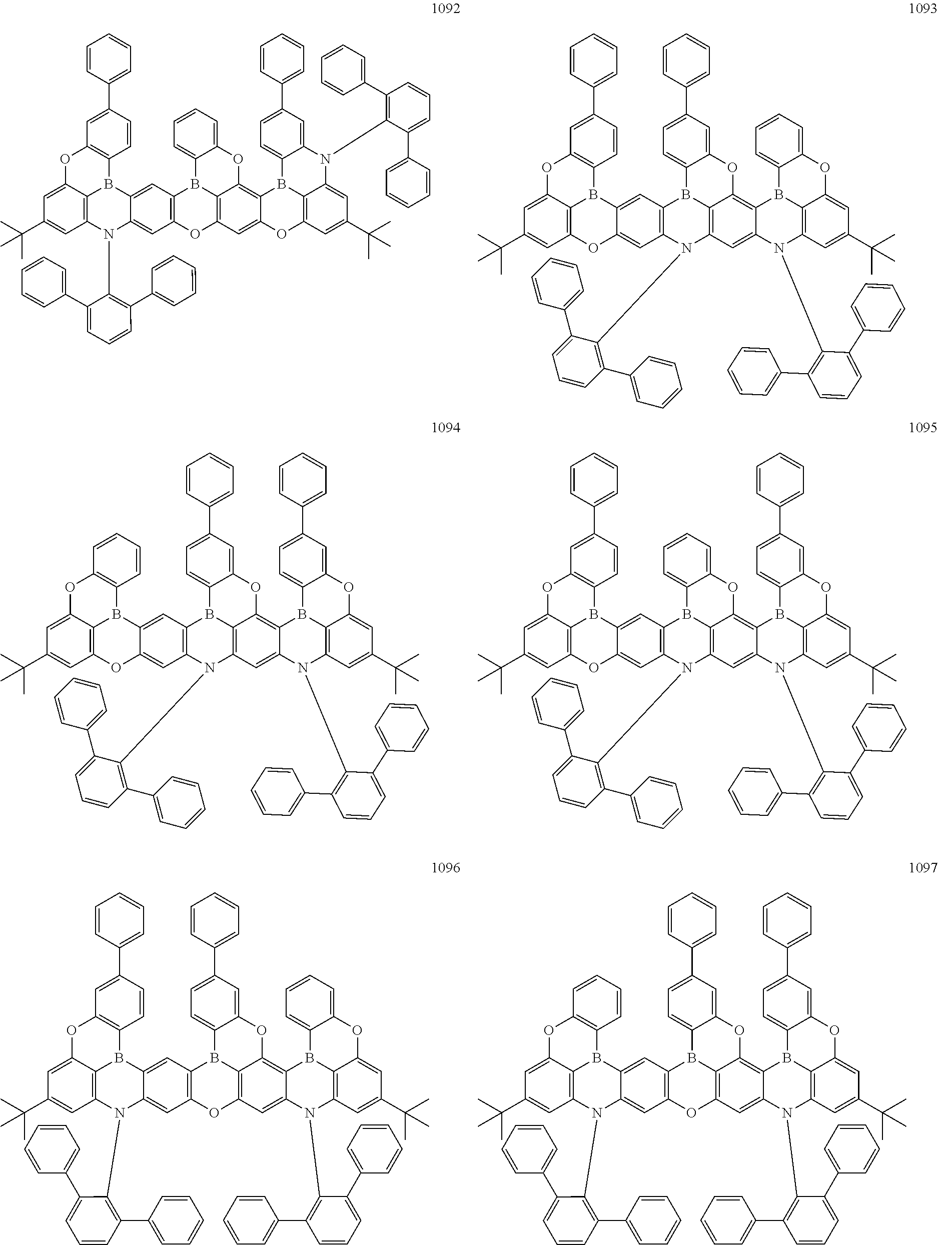 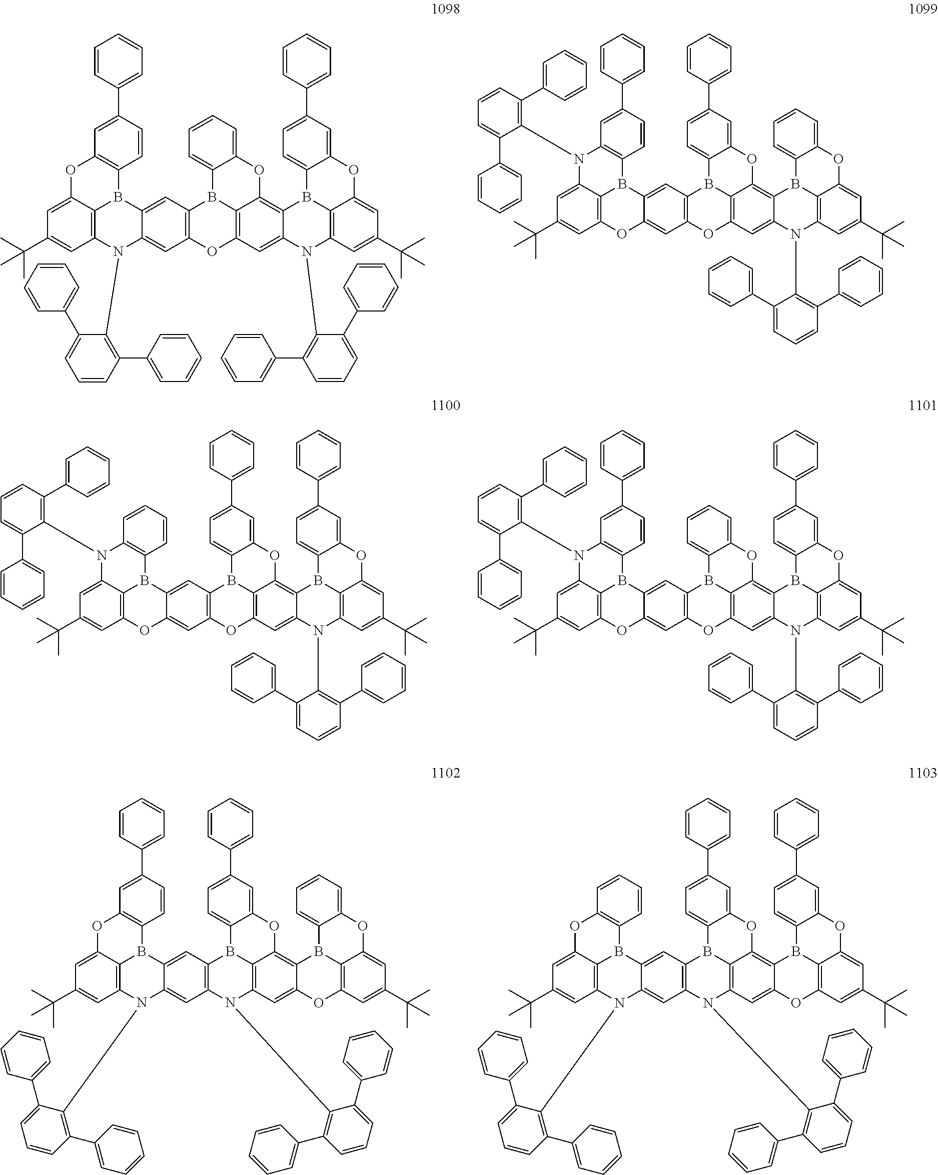 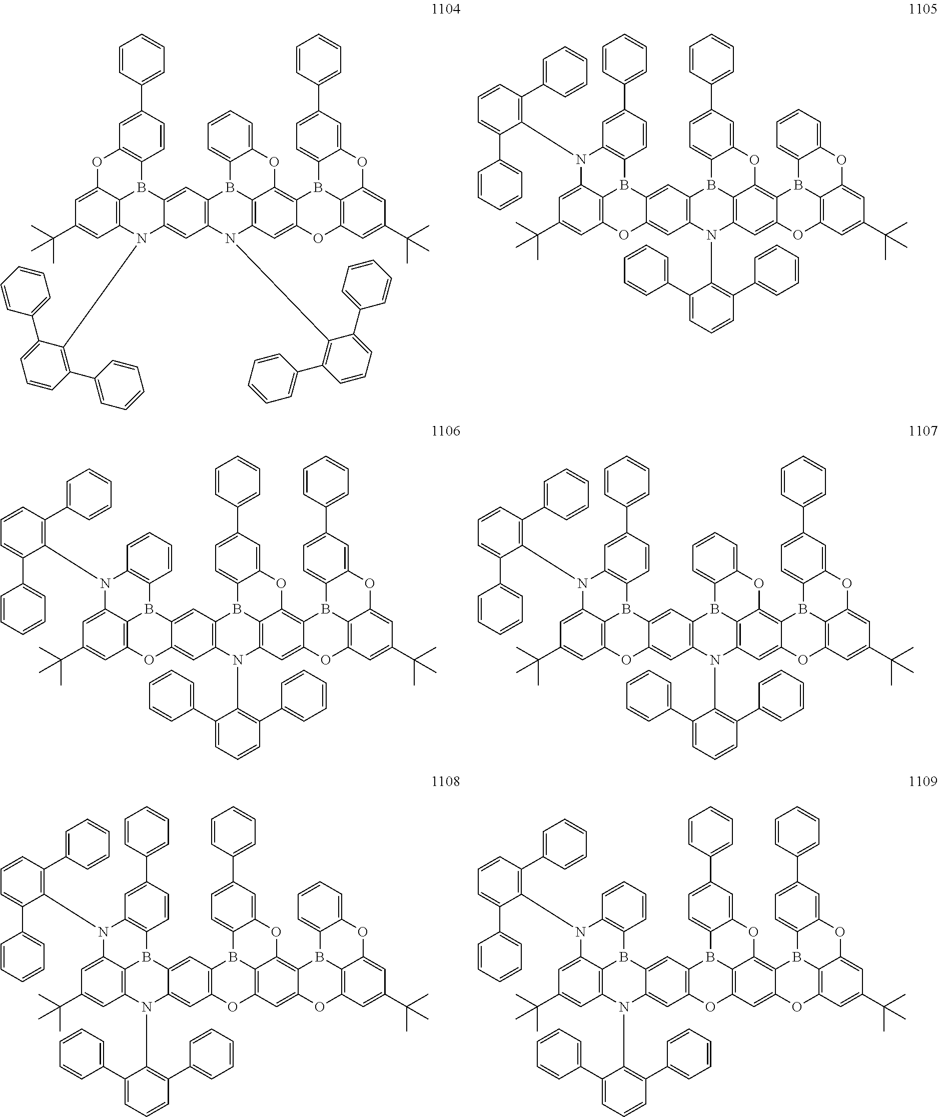 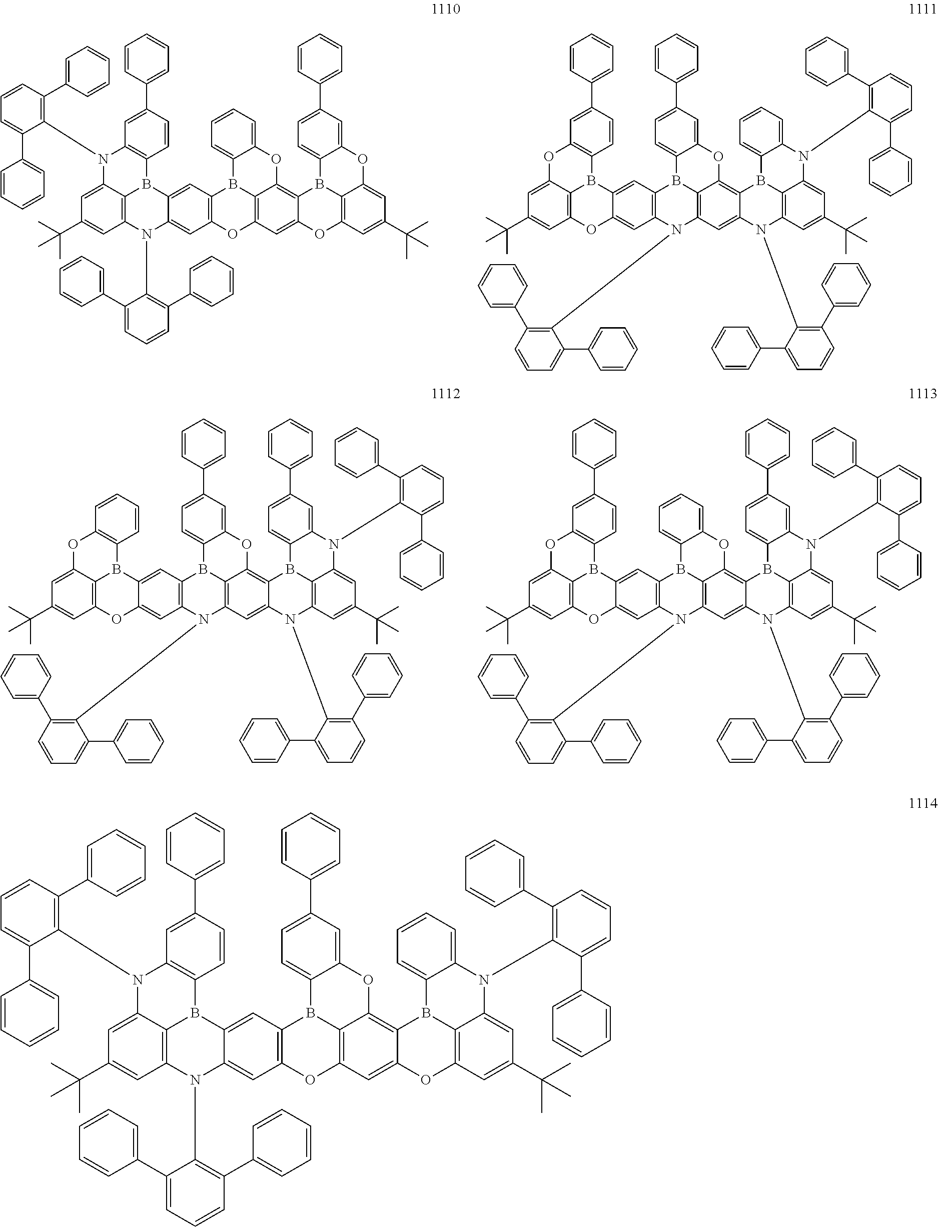 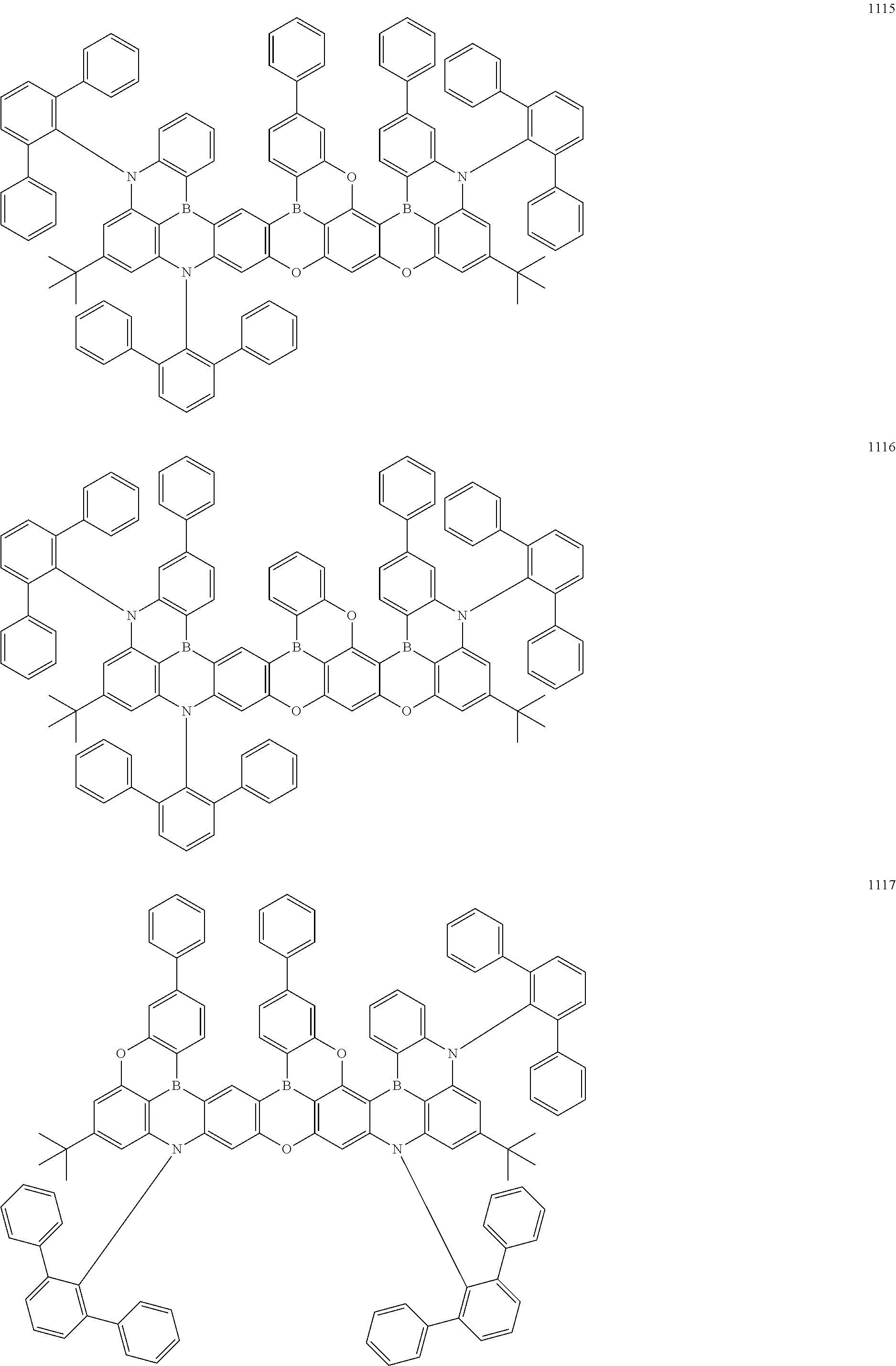 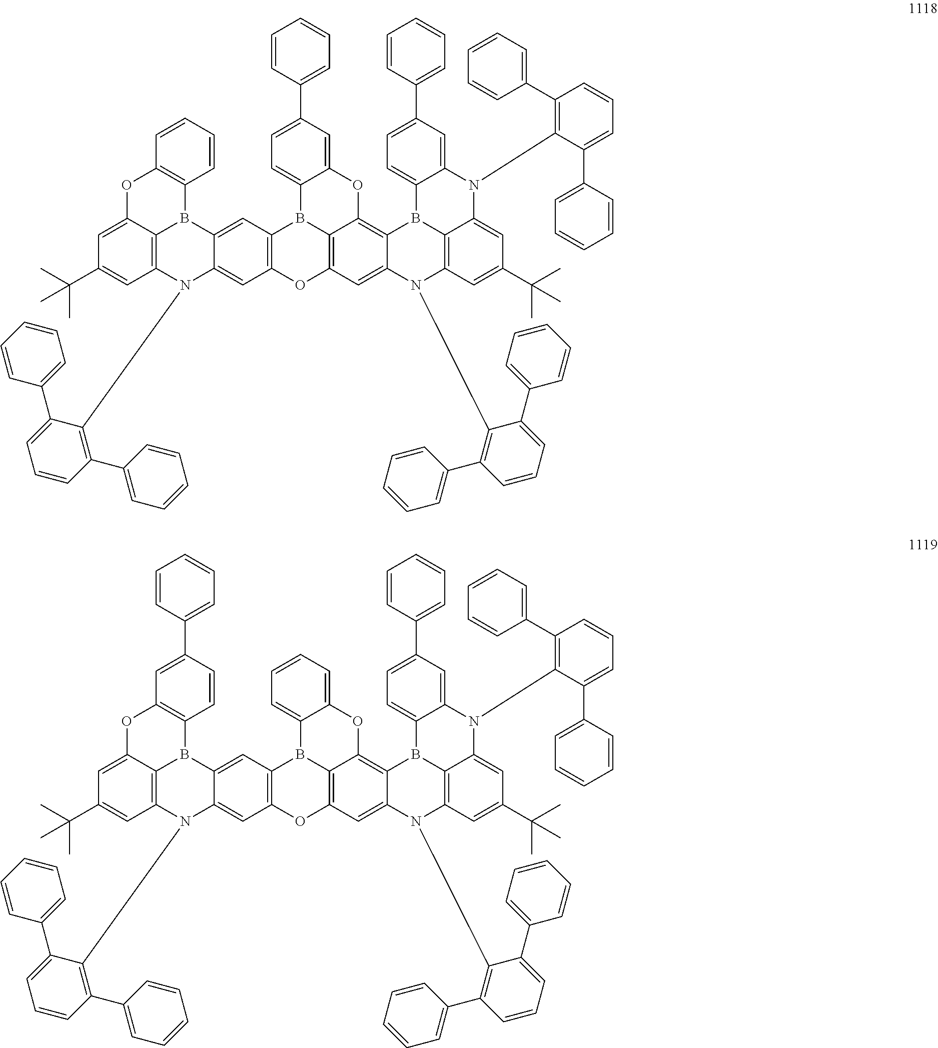 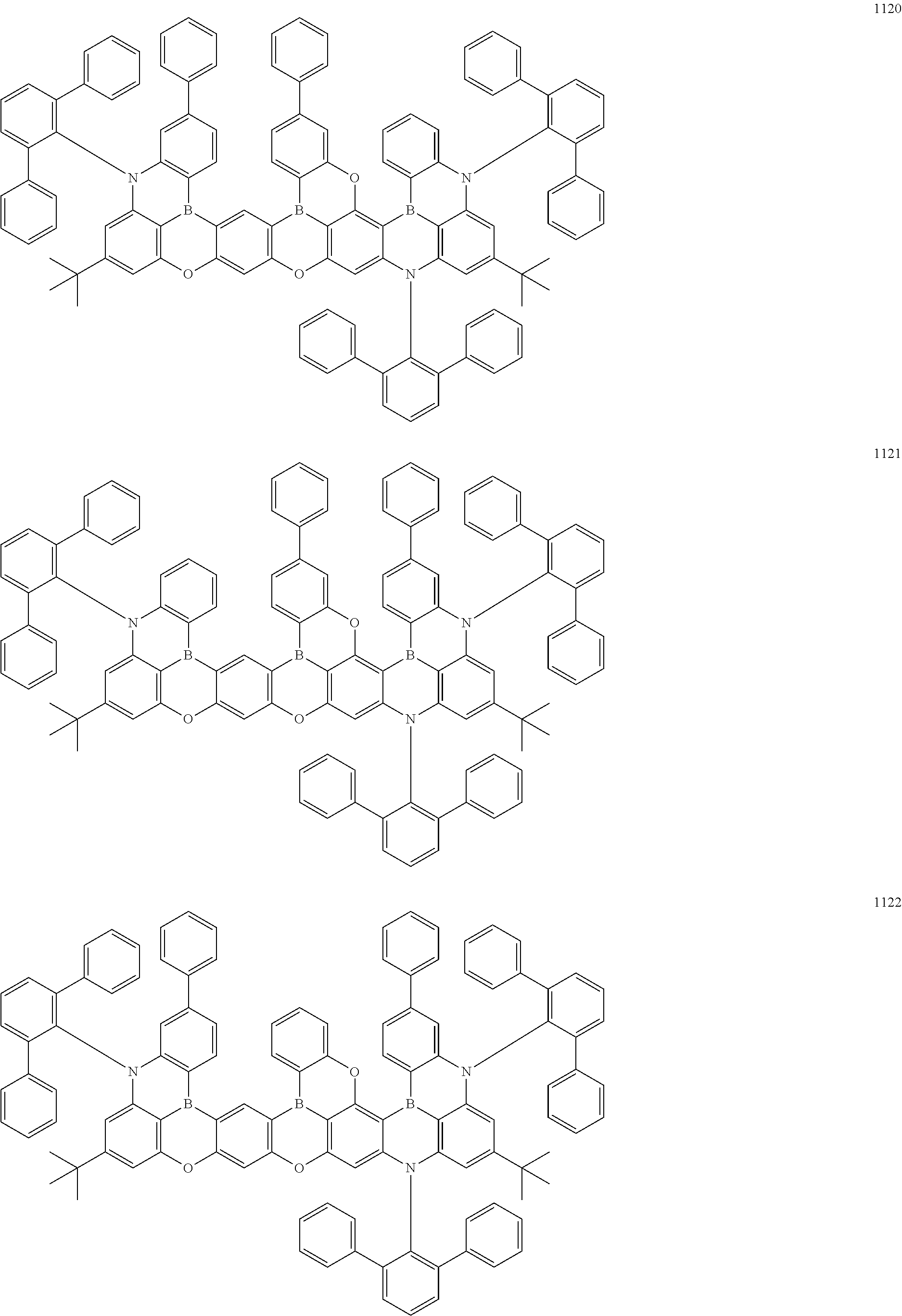 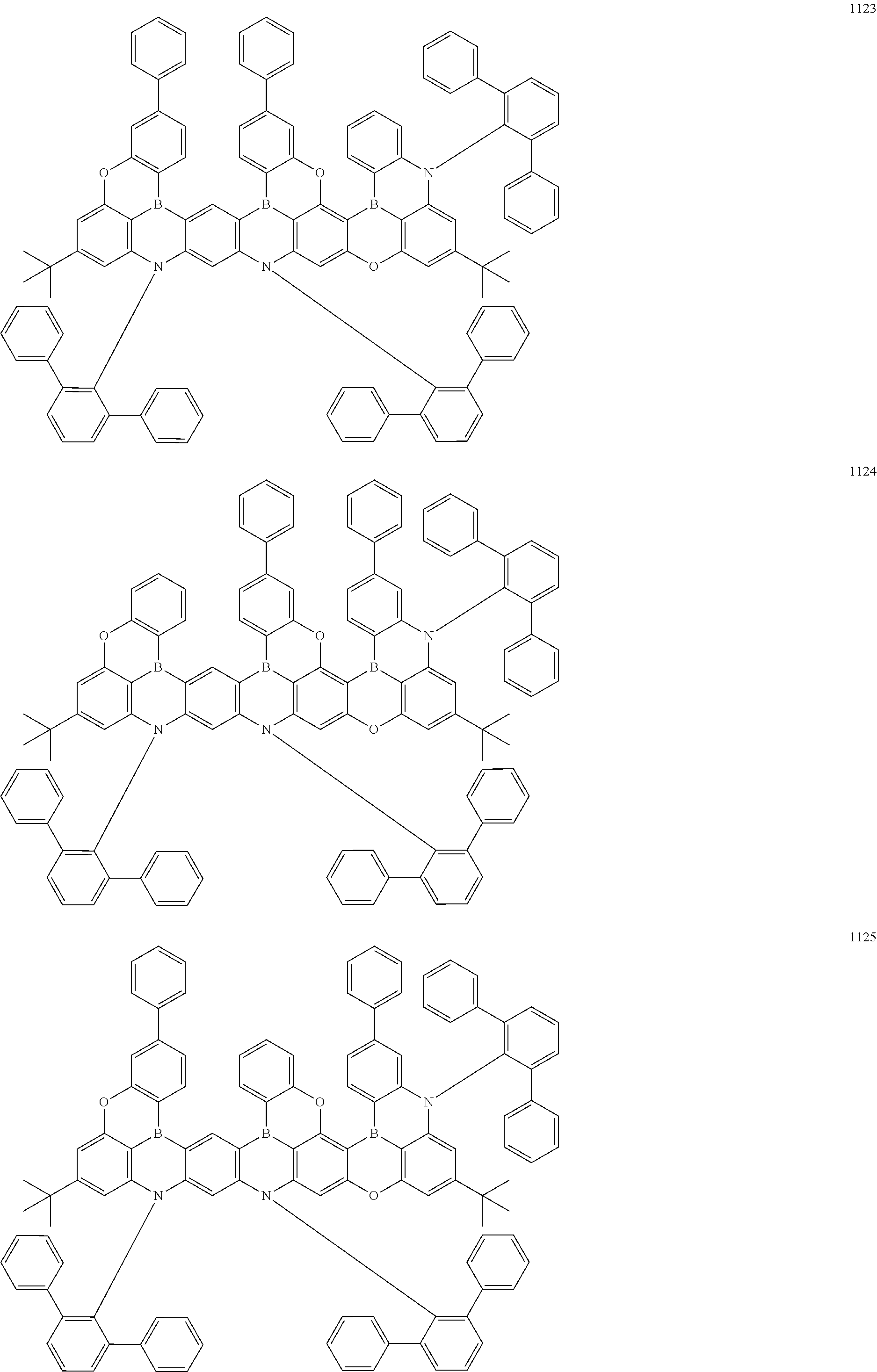 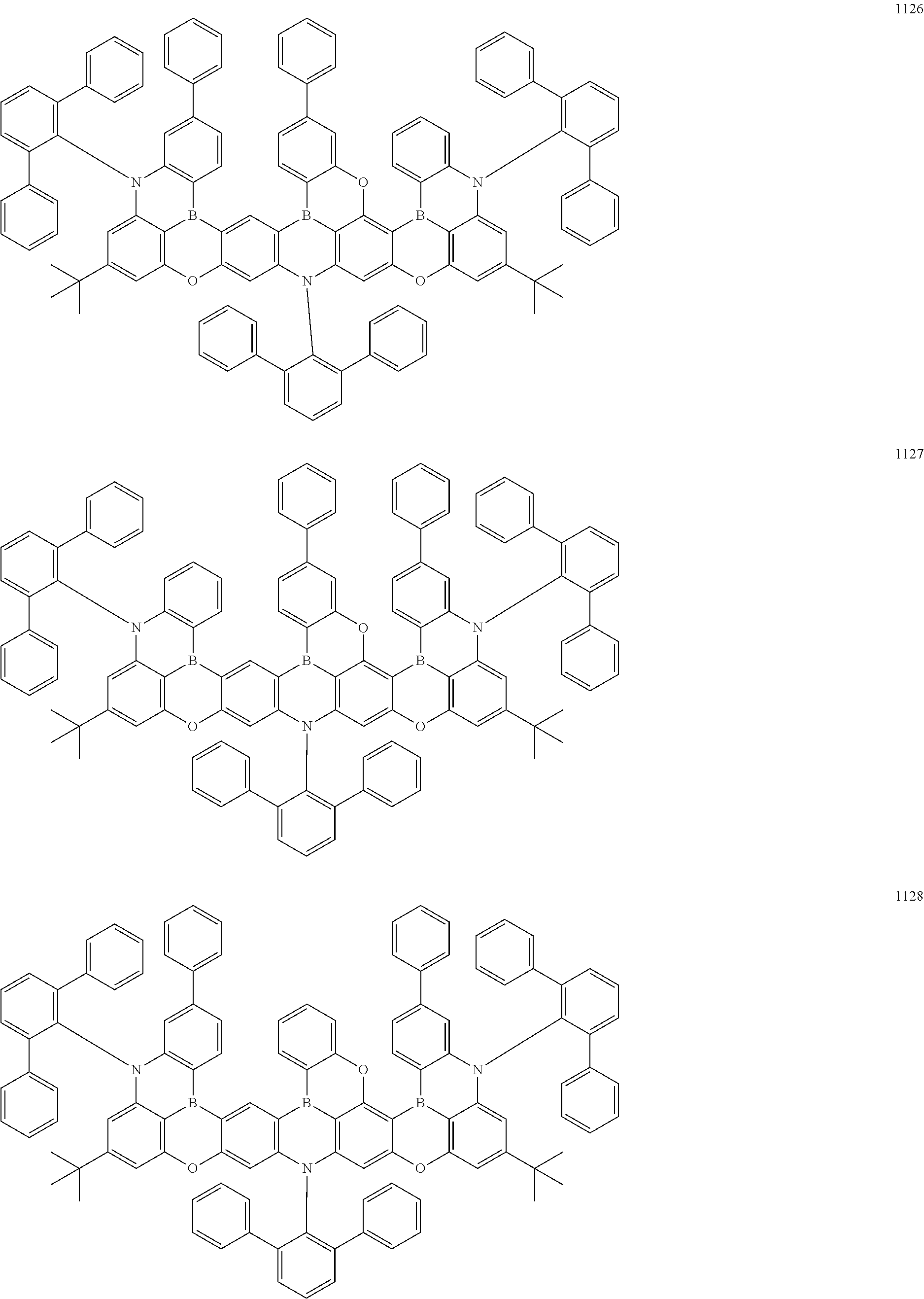 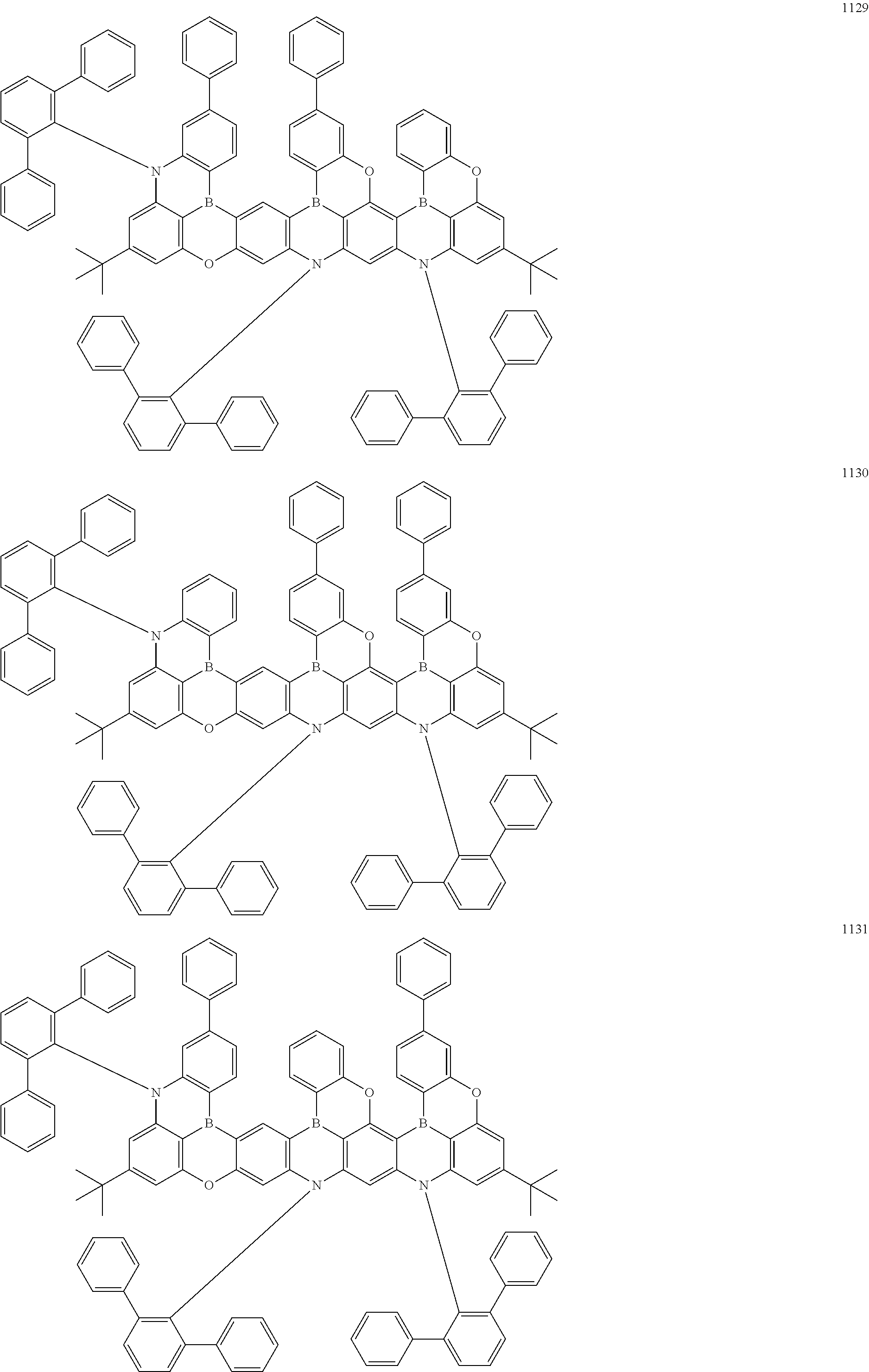 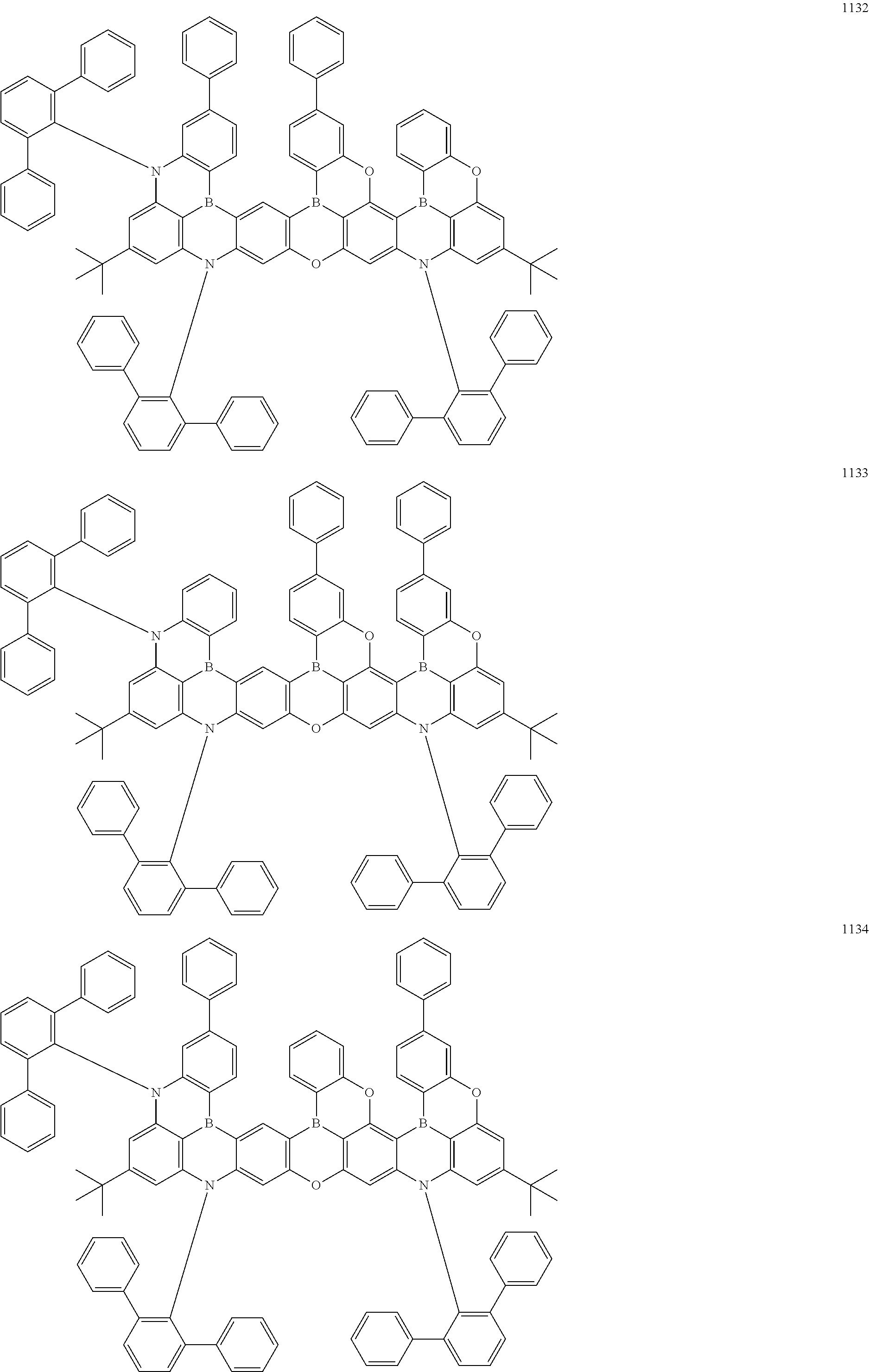 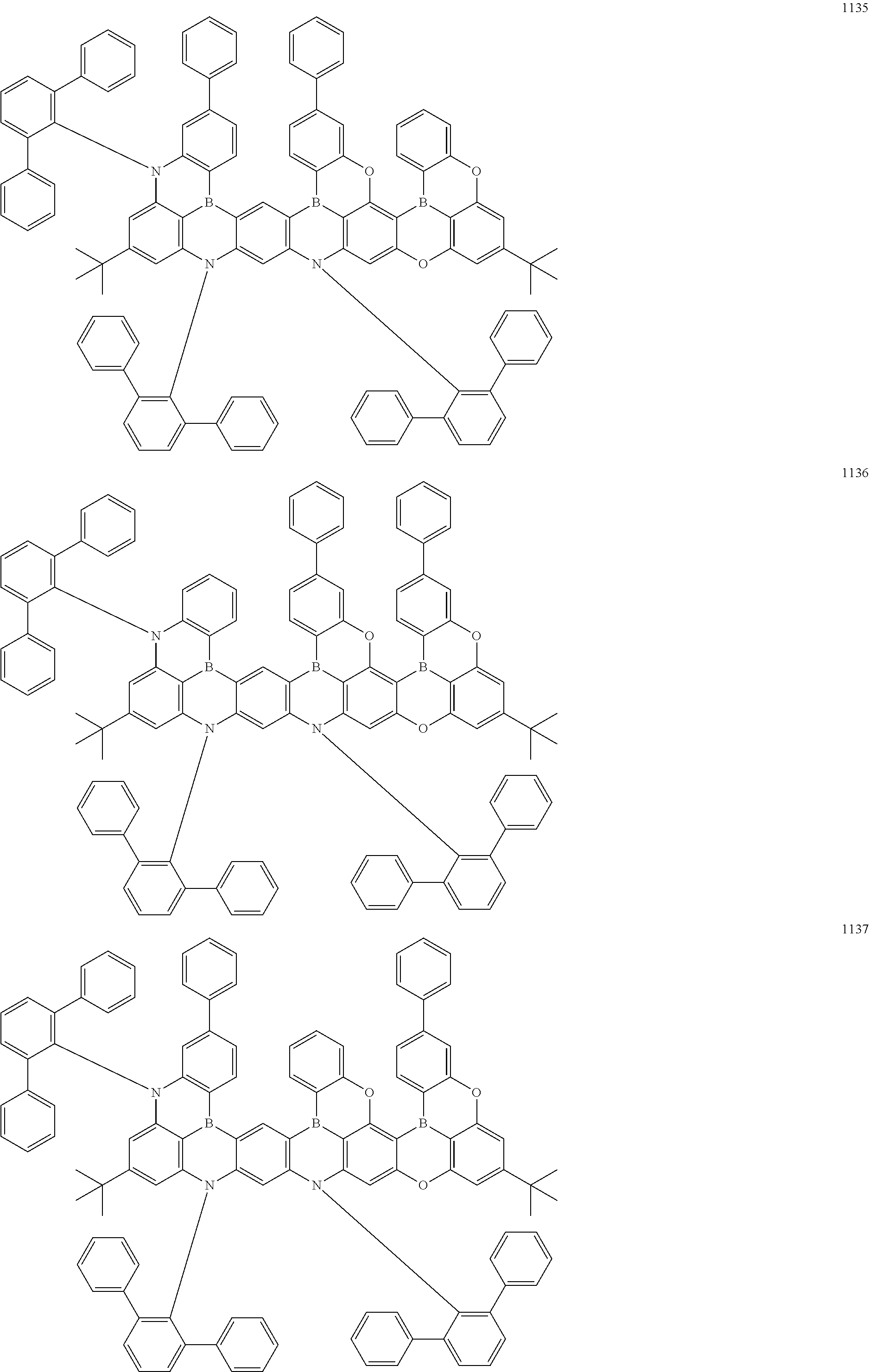 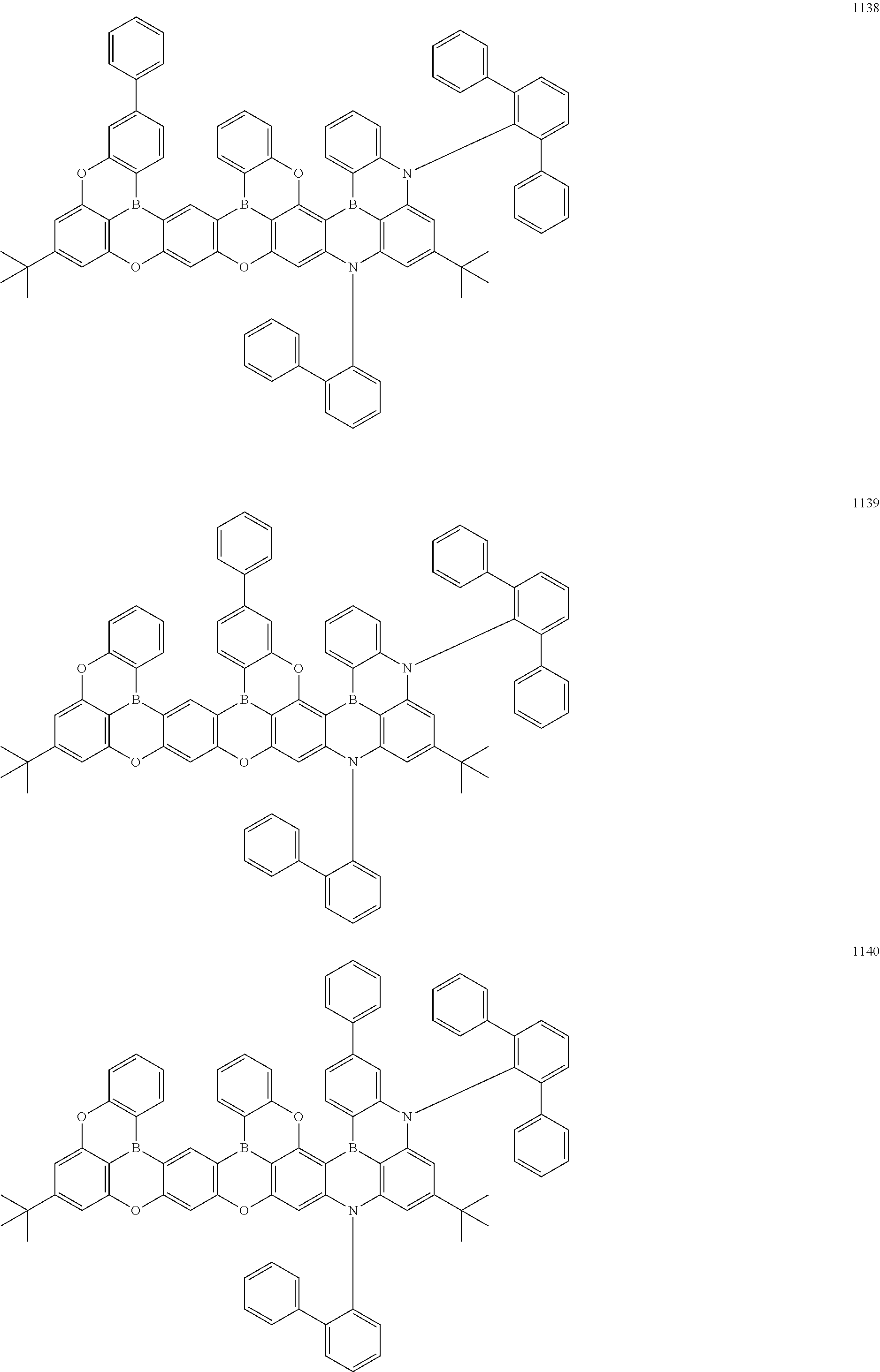 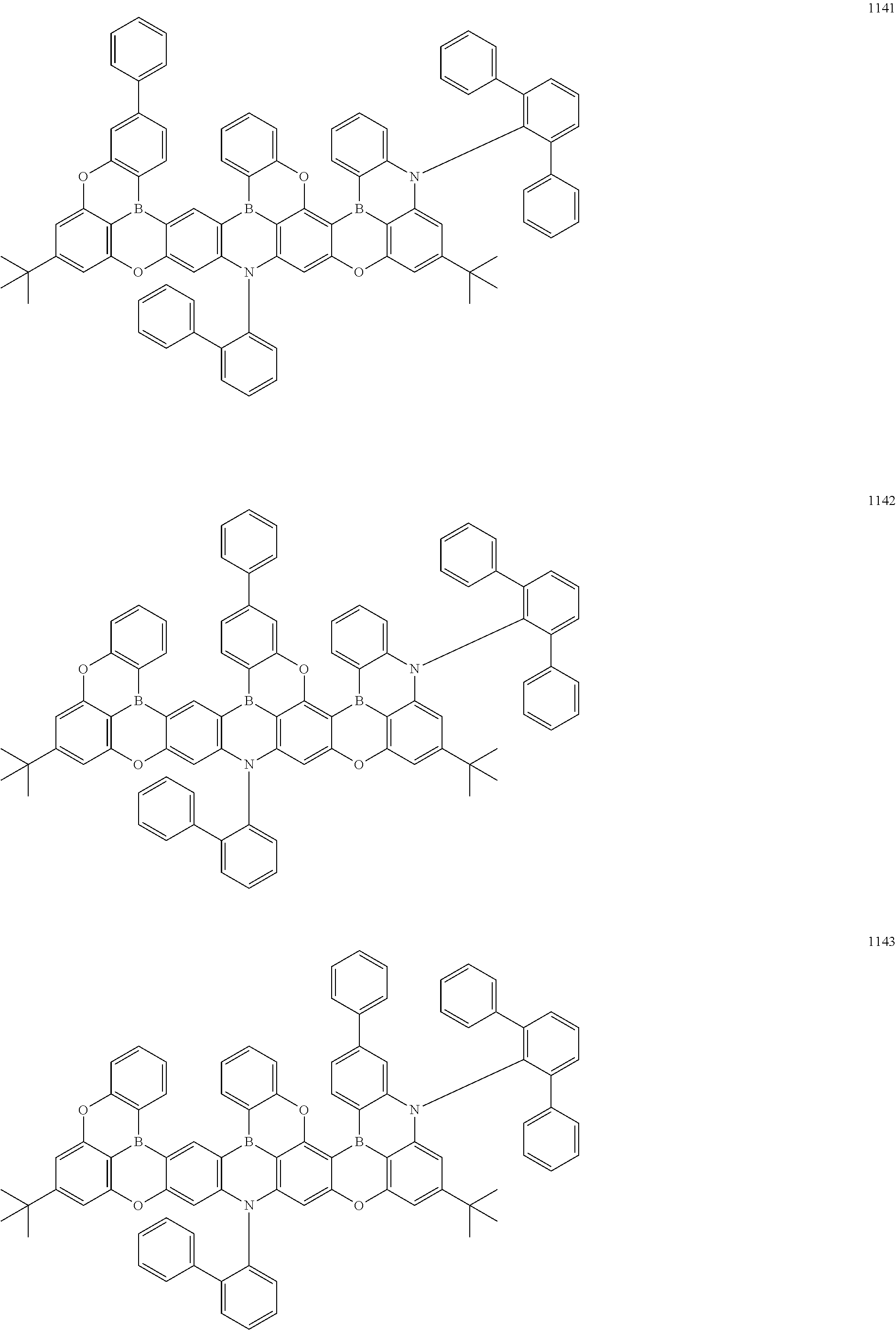 [SMILES: CC(C)(C)c1cc2c3c(c1)Oc1cc4c(cc1B3c1ccc(-c3ccccc3)cc1O2)B1c2ccccc2Oc2c3c(cc(c21)N4c1ccccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccc(-c3ccccc3)cc2Oc2c3c(cc(c21)N4c1ccccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccccc2Oc2c3c(cc(c21)N4c1ccccc1-c1ccccc1)Oc1cc(C(C)(C)C)cc2c1B3c1ccc(-c3ccccc3)cc1N2c1c(-c2ccccc2)cccc1-c1ccccc1] 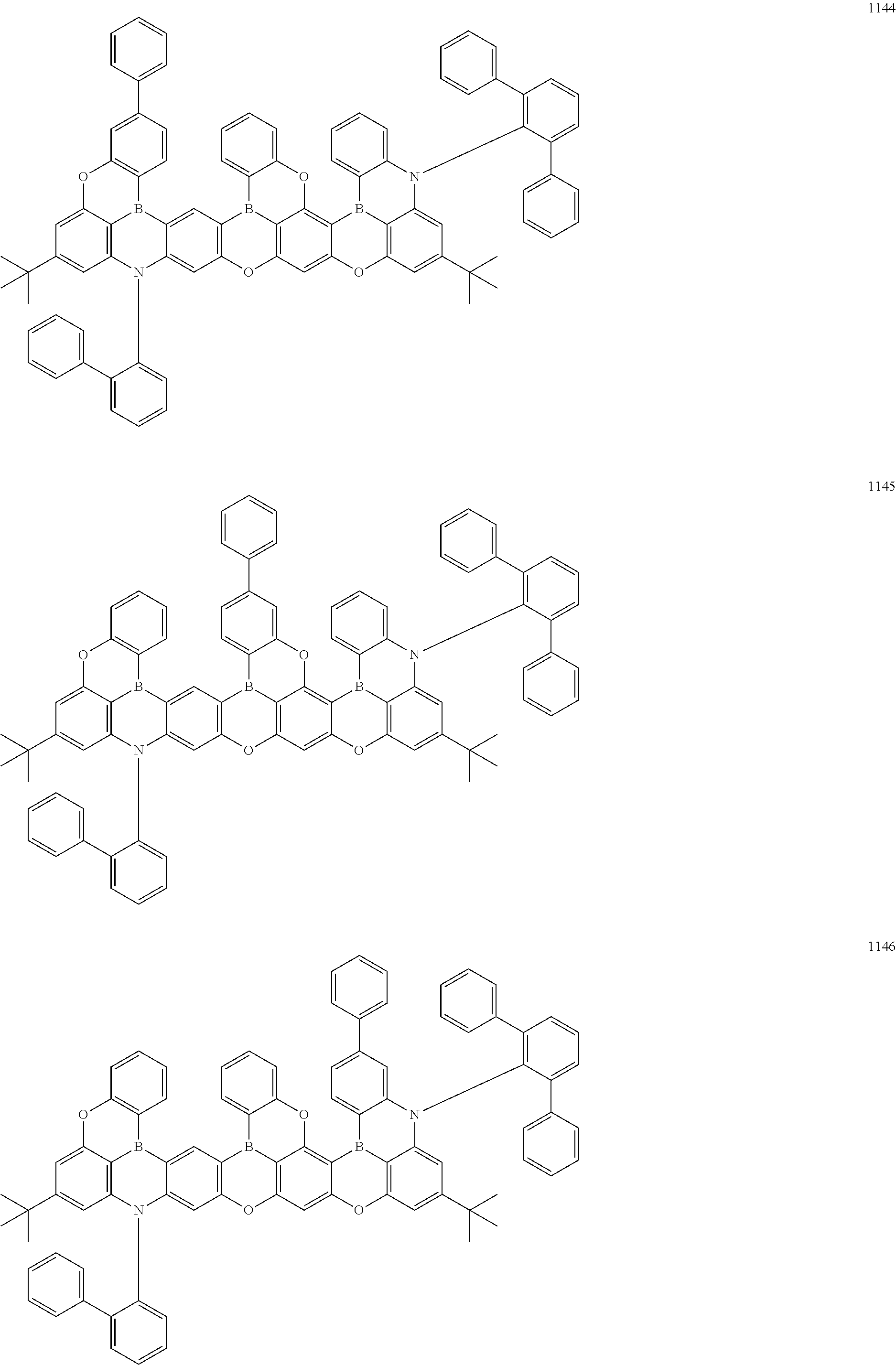 [SMILES: CC(C)(C)c1cc2c3c(c1)N(c1ccccc1-c1ccccc1)c1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)O1)O4 ; CC(C)(C)c1cc2c3c(c1)N(c1ccccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)O1)O4 ; CC(C)(C)c1cc2c3c(c1)N(c1ccccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)O1)O4] 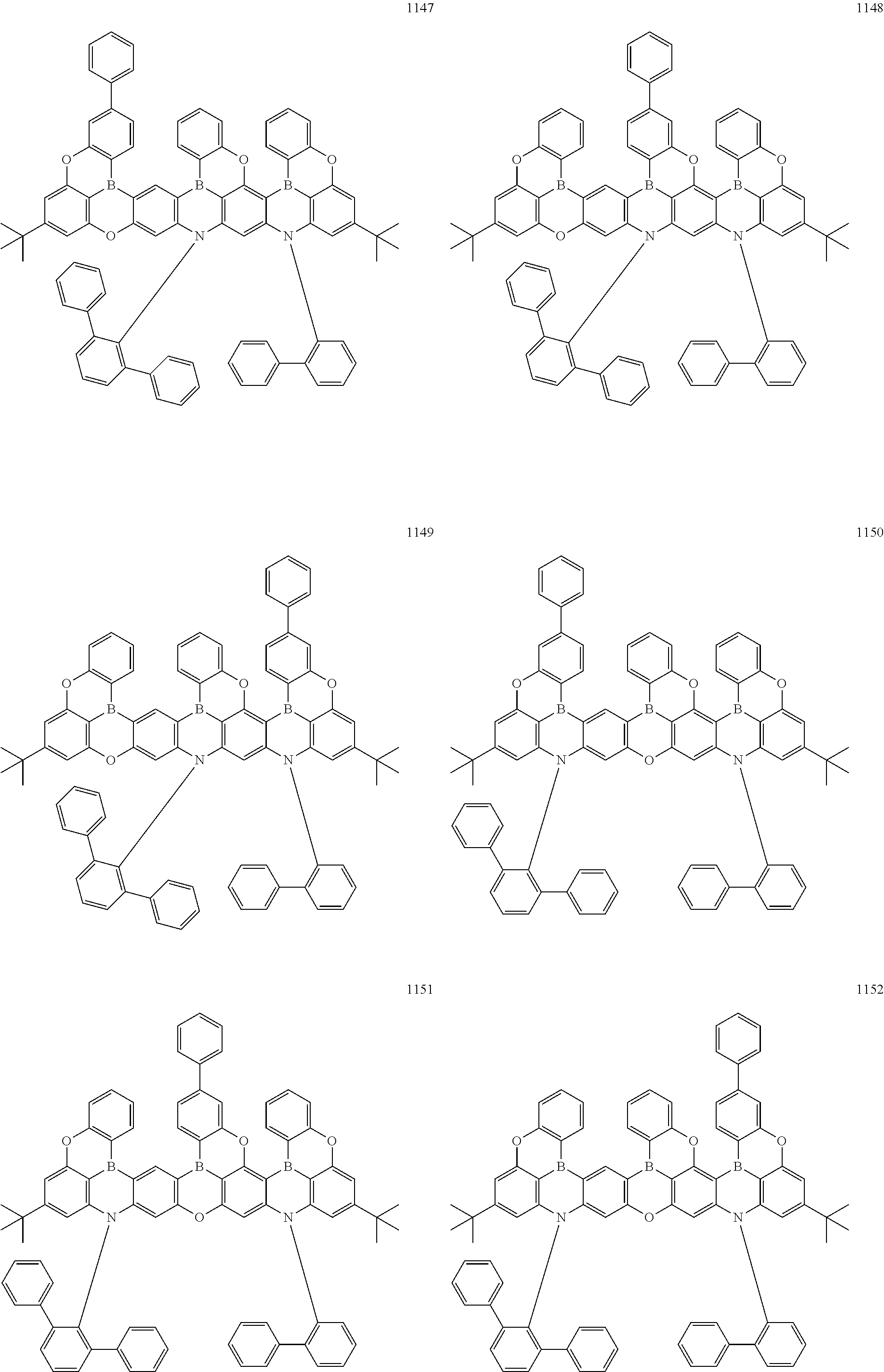 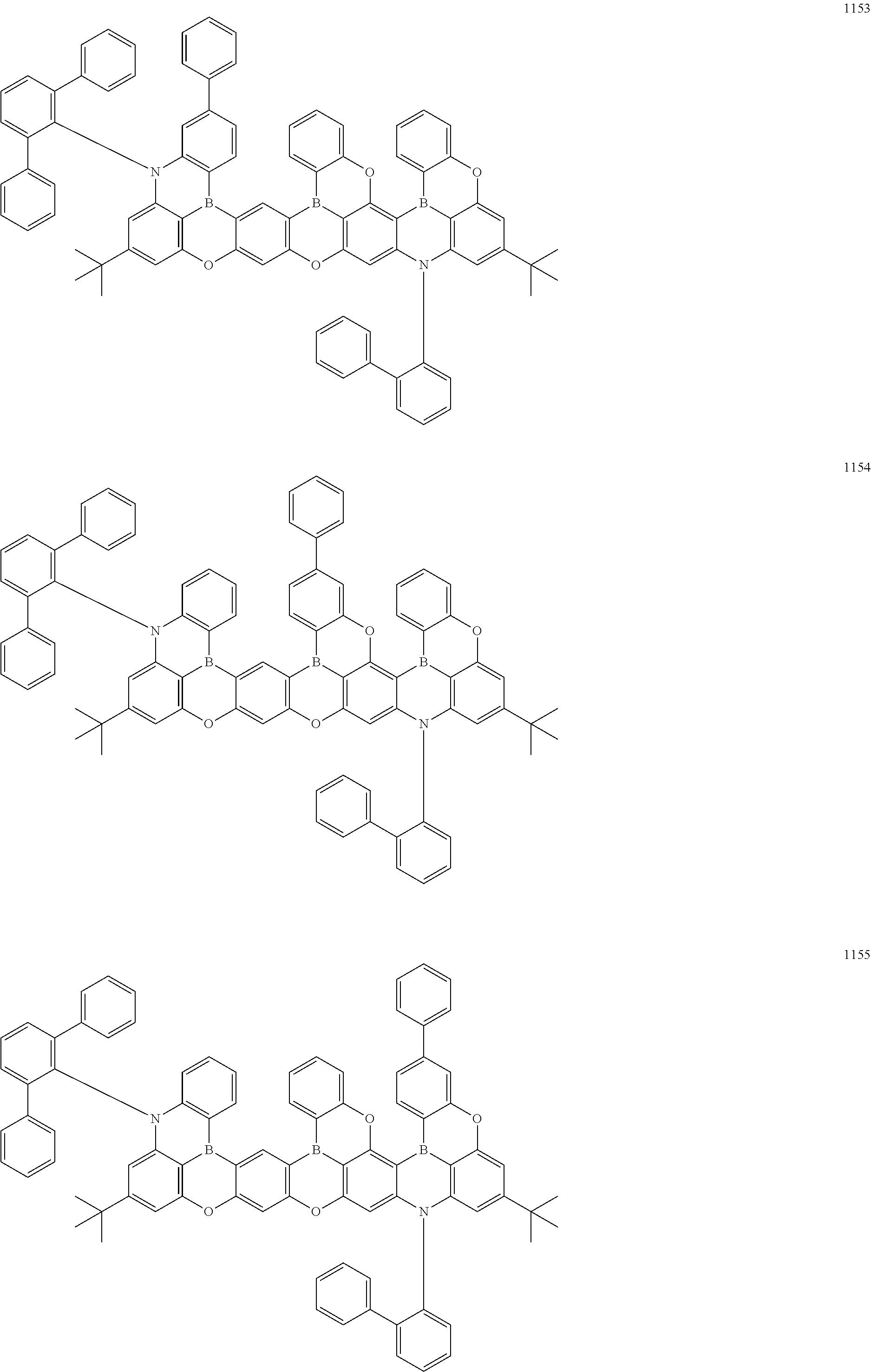 [SMILES: CC(C)(C)c1cc2c3c(c1)N(c1ccccc1-c1ccccc1)c1cc4c5c(c1B3c1ccccc1O2)Oc1ccccc1B5c1cc2c(cc1O4)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1ccccc1-c1ccccc1)c1cc4c5c(c1B3c1ccccc1O2)Oc1cc(-c2ccccc2)ccc1B5c1cc2c(cc1O4)Oc1cc(C(C)(C)C)cc3c1B2c1ccccc1N3c1c(-c2ccccc2)cccc1-c1ccccc1 ; CC(C)(C)c1cc2c3c(c1)N(c1ccccc1-c1ccccc1)c1cc4c5c(c1B3c1ccc(-c3ccccc3)cc1O2)Oc1ccccc1B5c1cc2c(cc1O4)Oc1cc(C(C)(C)C)cc3c1B2c1ccccc1N3c1c(-c2ccccc2)cccc1-c1ccccc1] 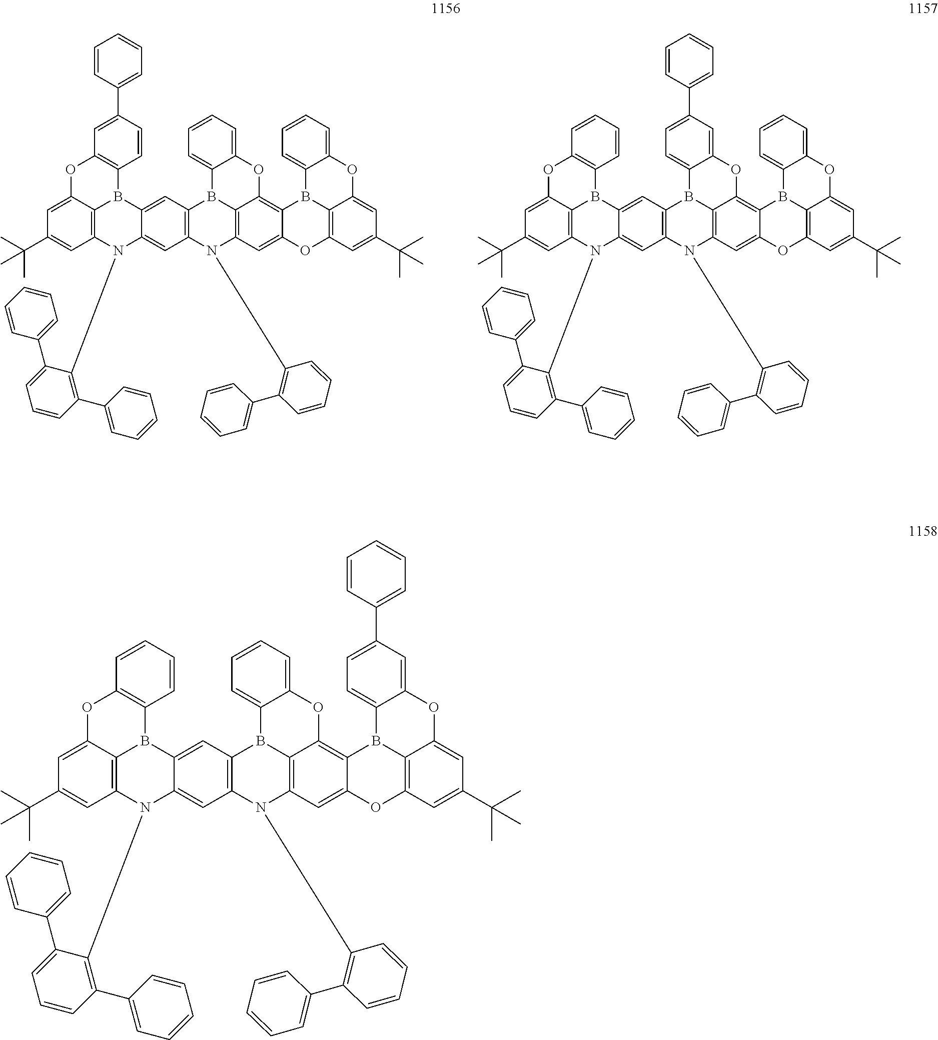 [SMILES: CC(C)(C)c1cc2c3c(c1)Oc1cc4c5c(c1B3c1ccccc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-c2ccccc2)cc1O3 ; CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)N(c1c(-c3ccccc3)cccc1-c1ccccc1)c1cc(C(C)(C)C)cc3c1B2c1ccccc1O3 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccccc1O3] 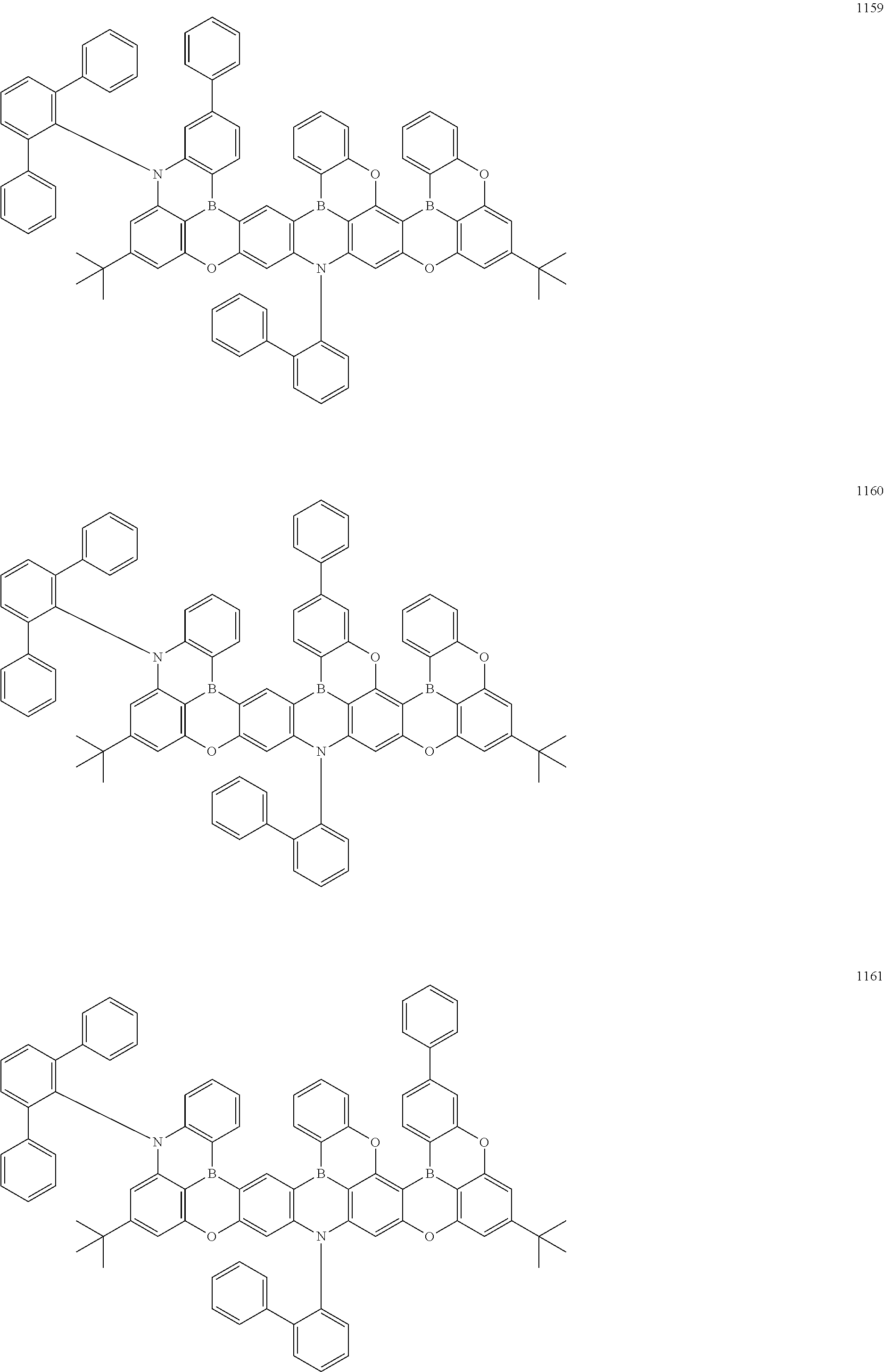 [SMILES: CC(C)(C)c1cc2c3c(c1)Oc1cc4c5c(c1B3c1ccccc1O2)Oc1ccccc1B5c1cc2c(cc1N4c1ccccc1-c1ccccc1)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)Oc1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)Oc1cc(C(C)(C)C)cc3c1B2c1ccccc1N3c1c(-c2ccccc2)cccc1-c1ccccc1] 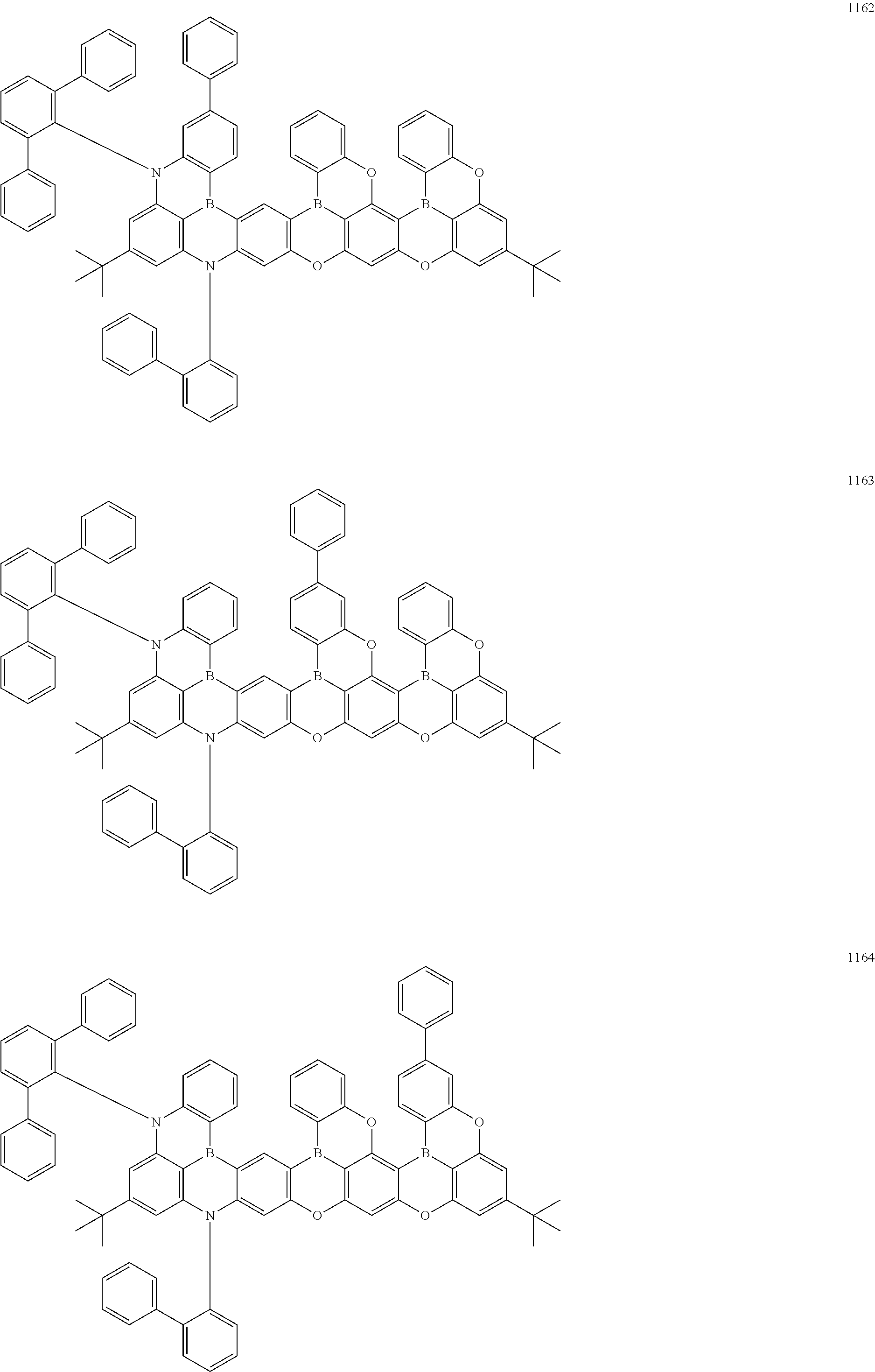 [SMILES: CC(C)(C)c1cc2c3c(c1)Oc1cc4c5c(c1B3c1ccccc1O2)Oc1ccccc1B5c1cc2c(cc1O4)N(c1ccccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1O4)N(c1ccccc1-c1ccccc1)c1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1O4)N(c1ccccc1-c1ccccc1)c1cc(C(C)(C)C)cc3c1B2c1ccccc1N3c1c(-c2ccccc2)cccc1-c1ccccc1] 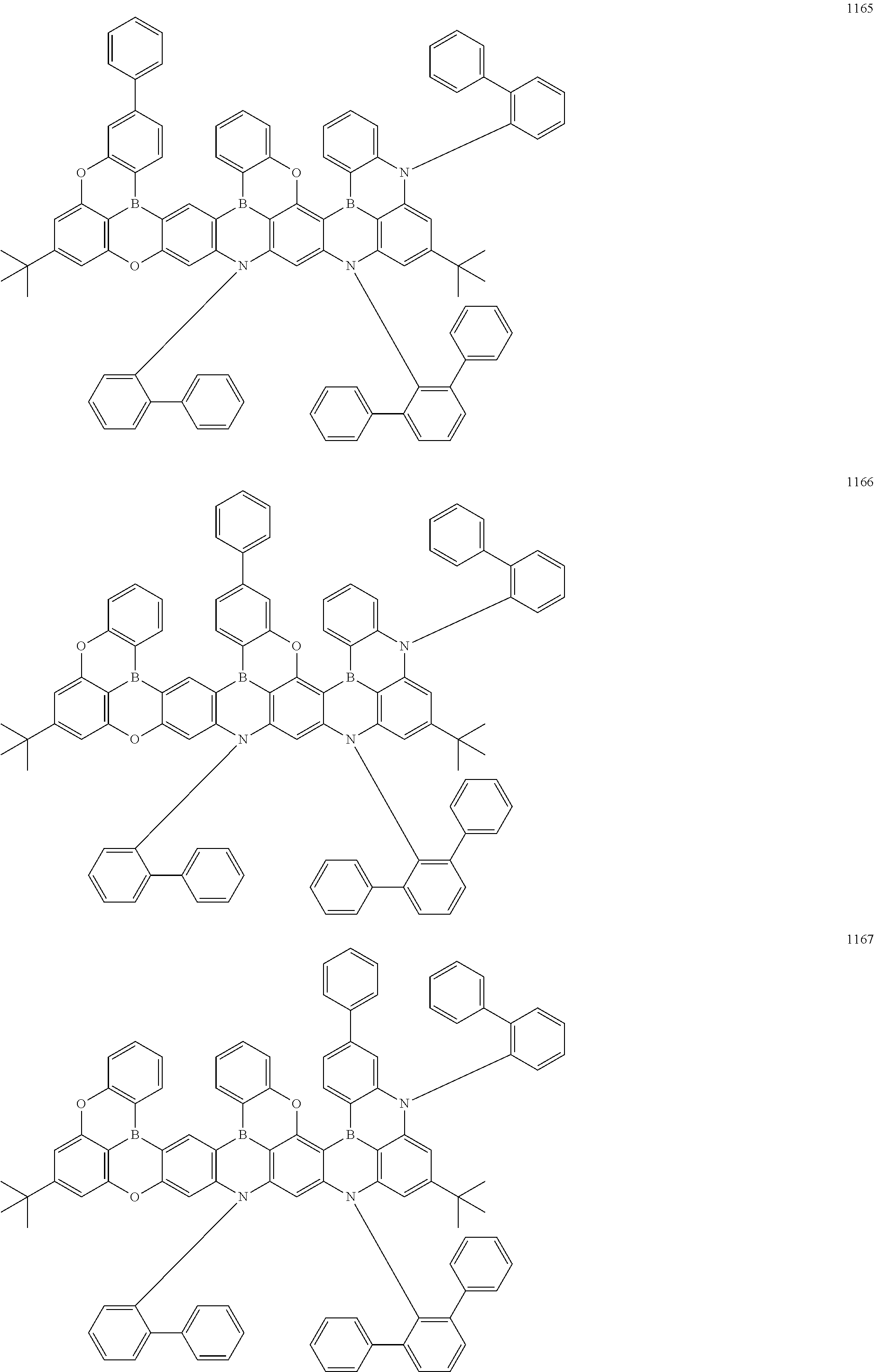 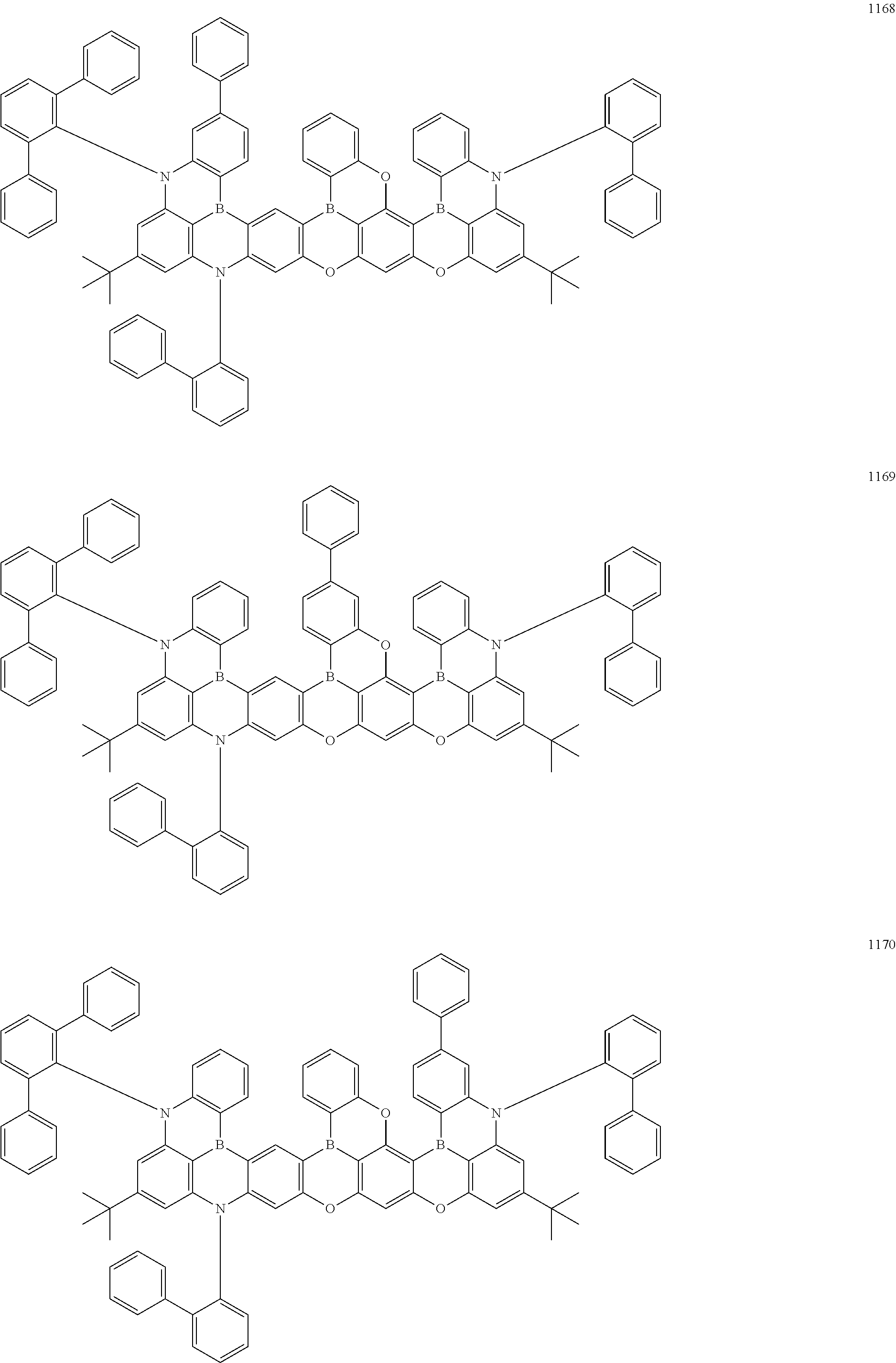 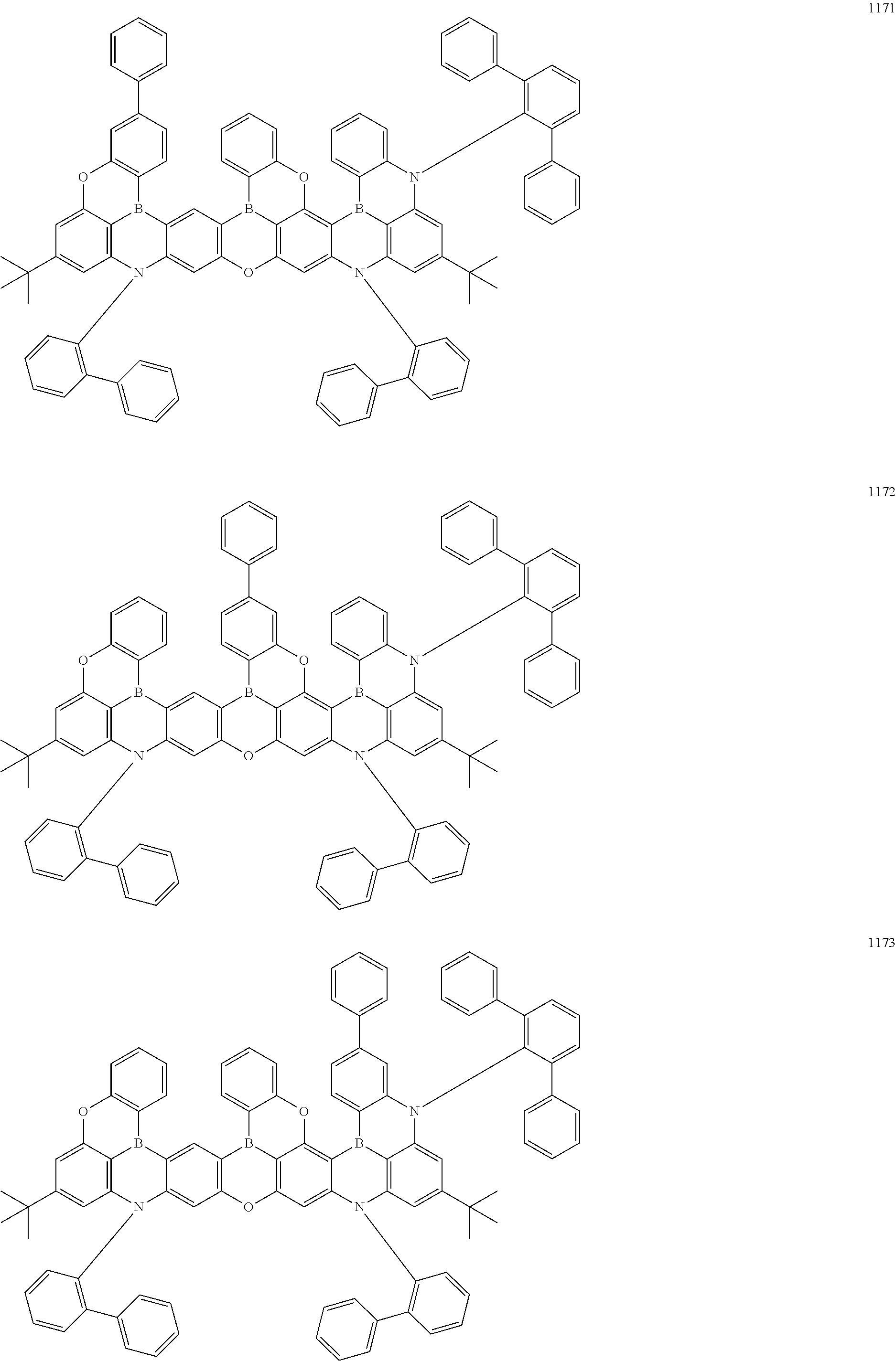 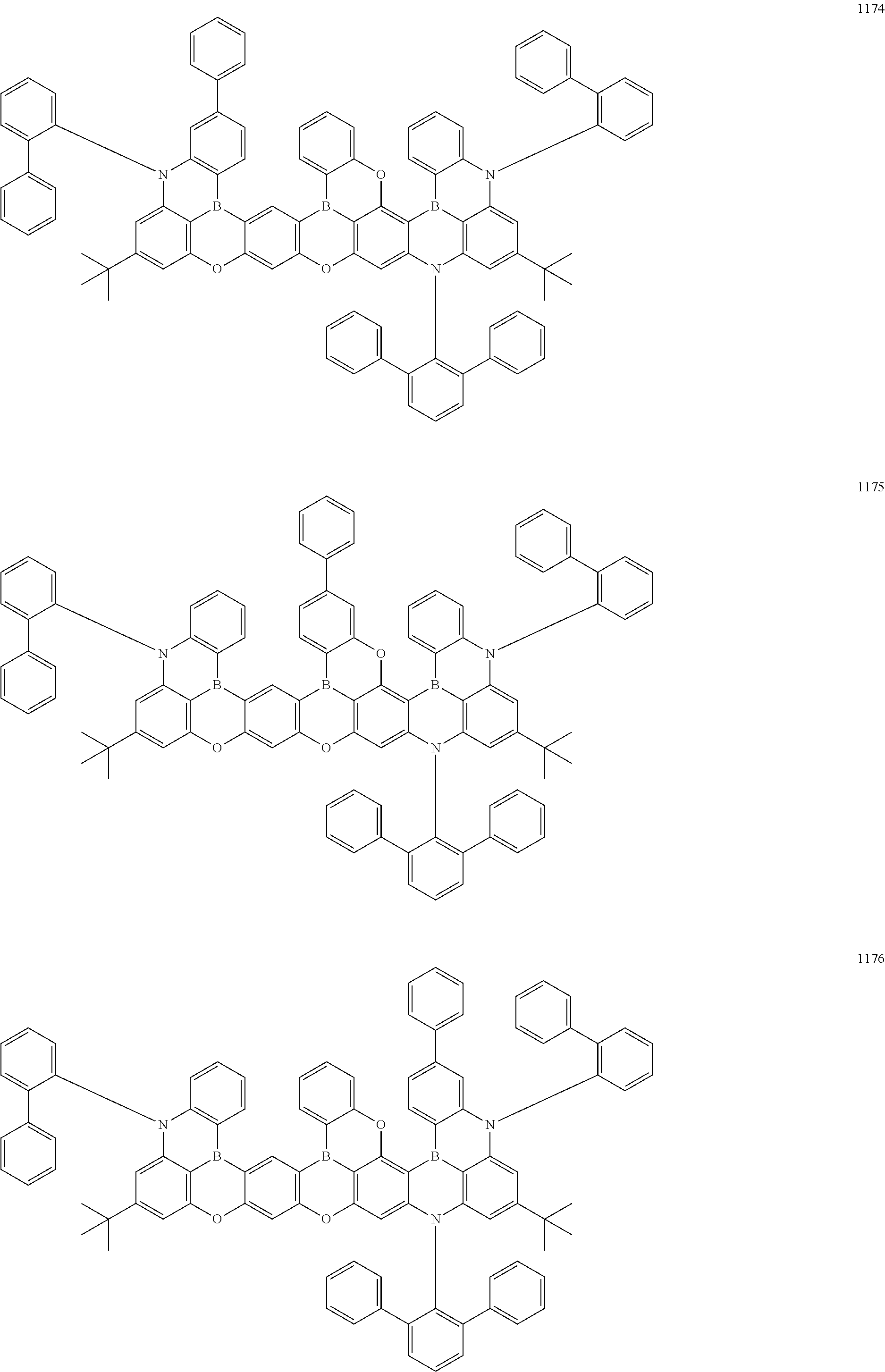 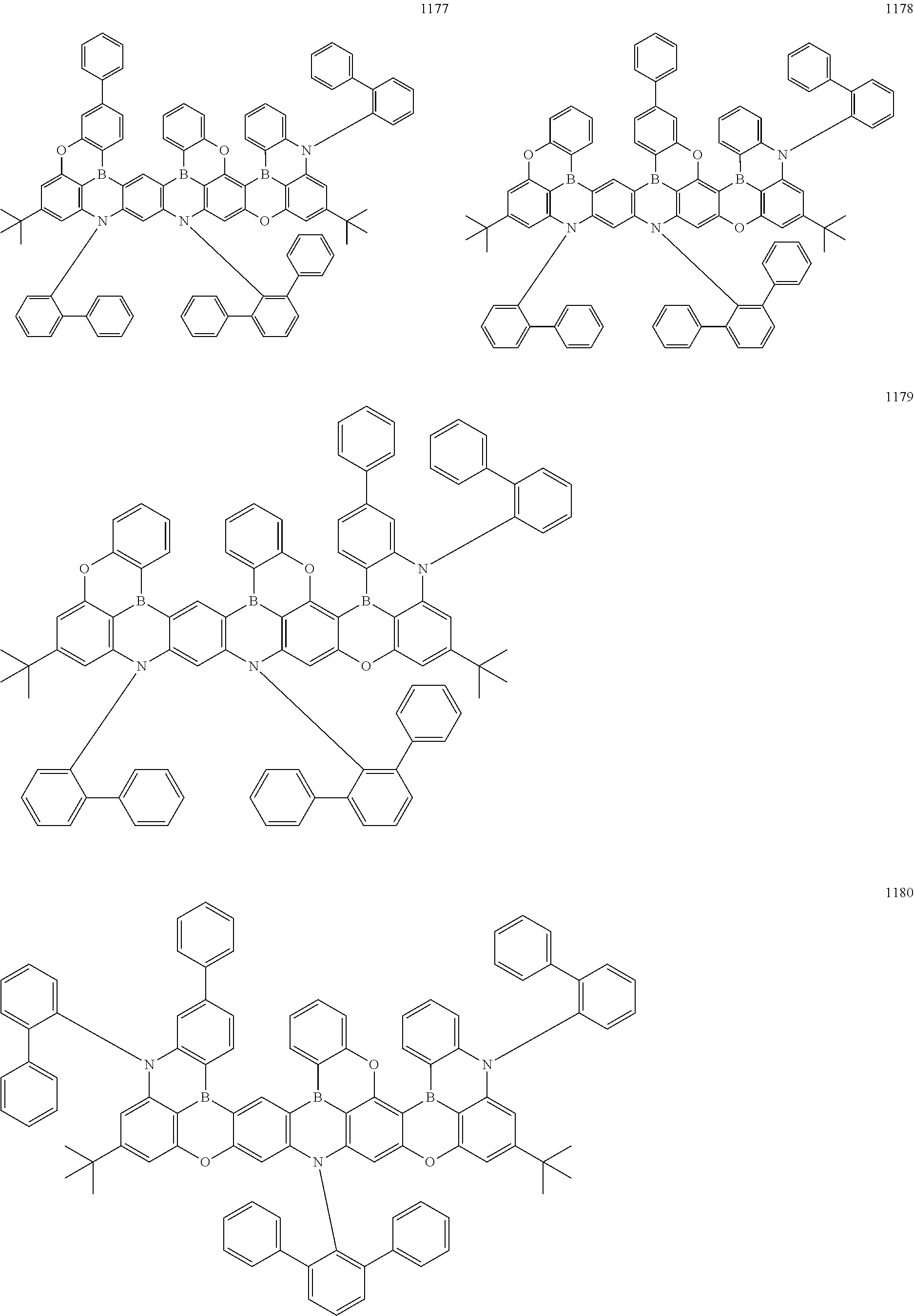 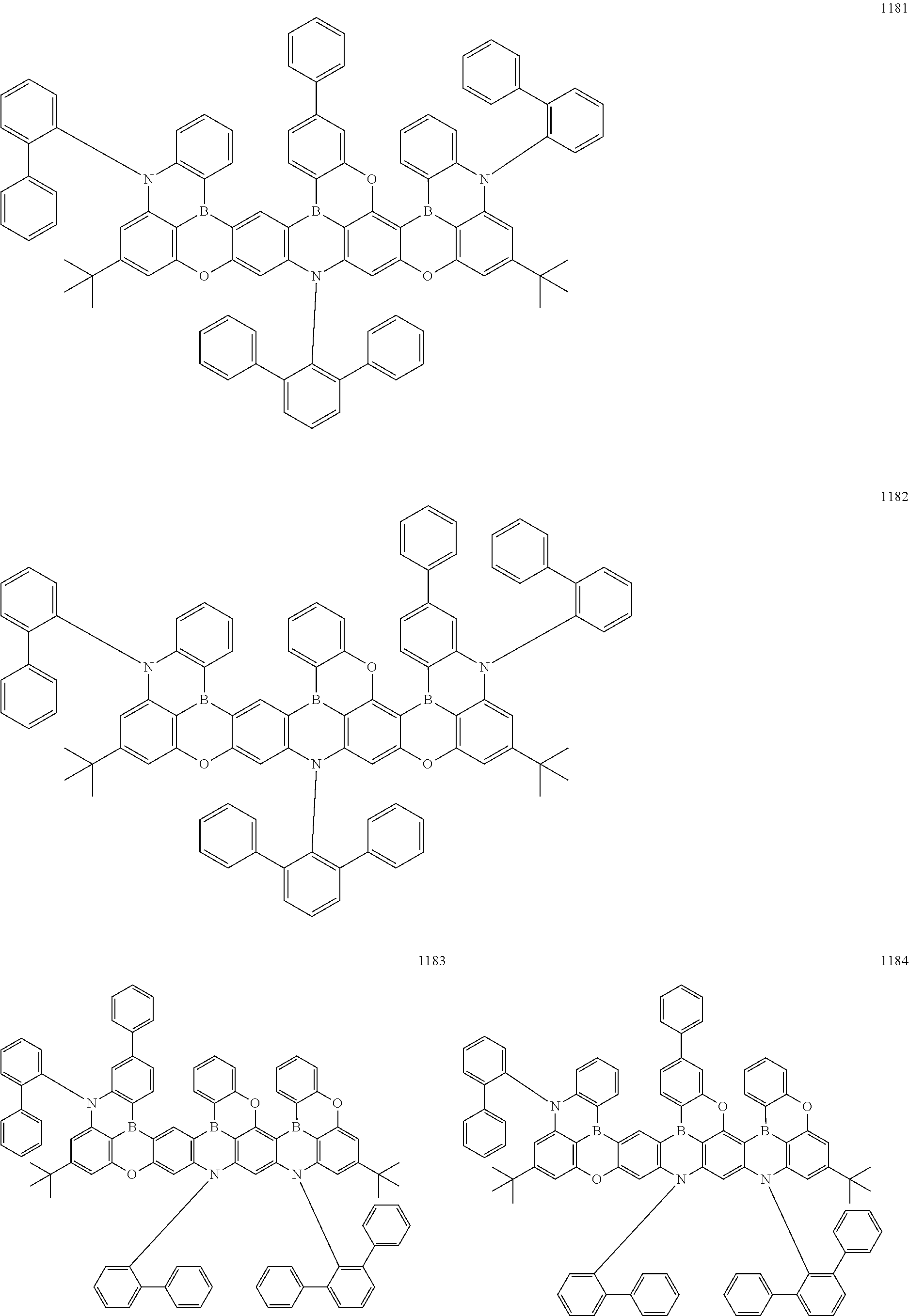 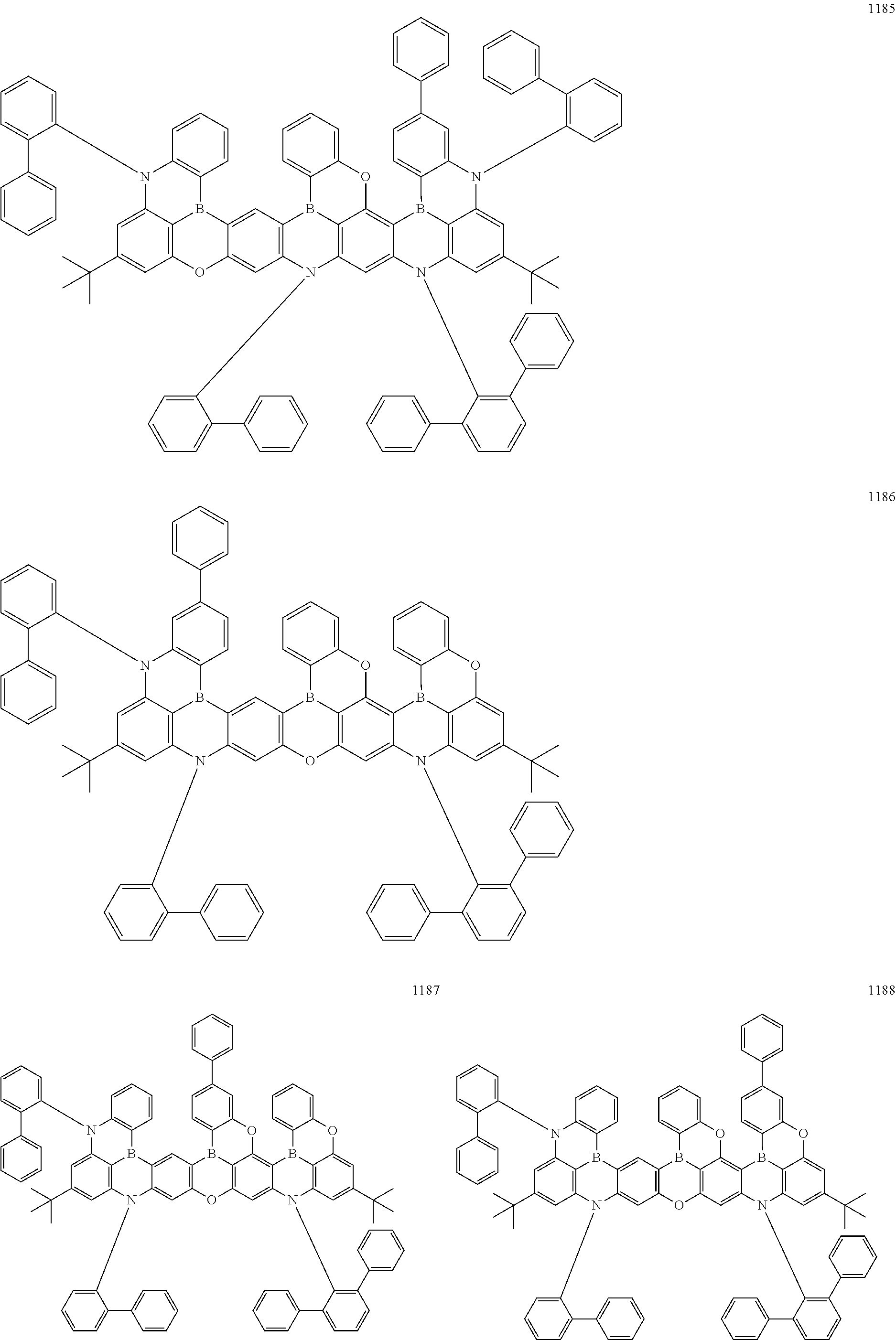 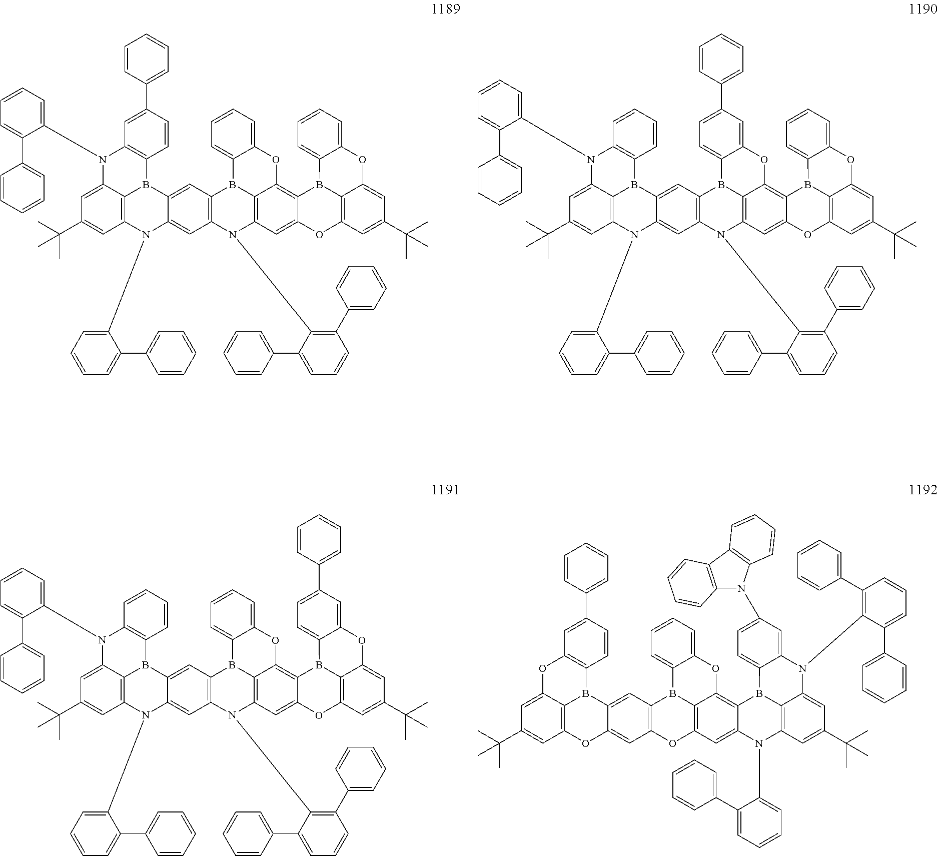 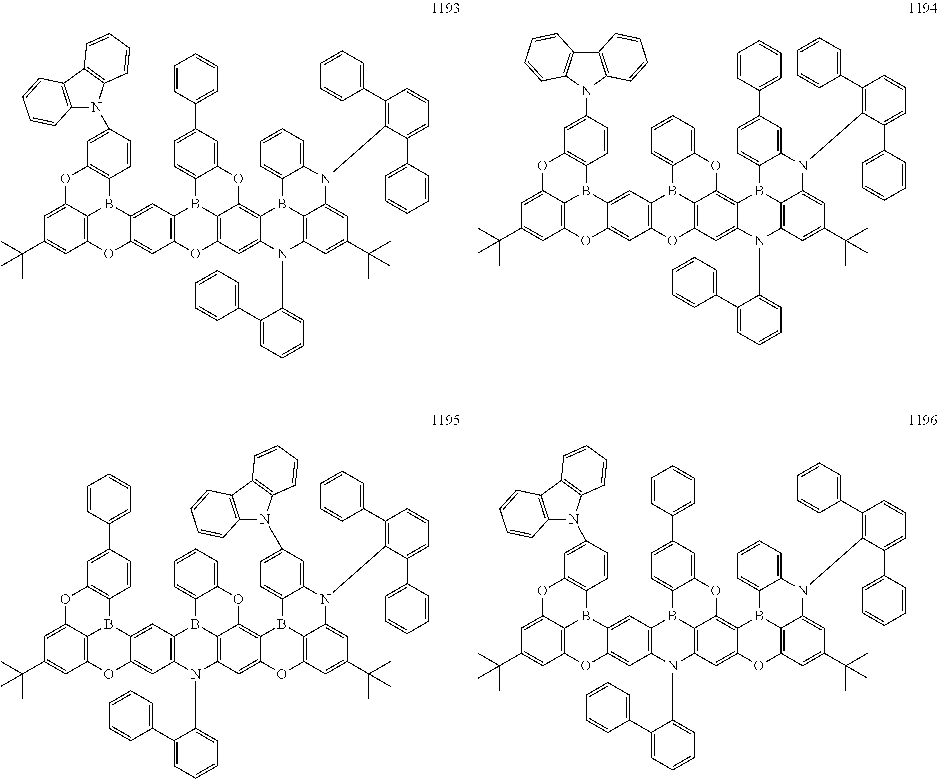 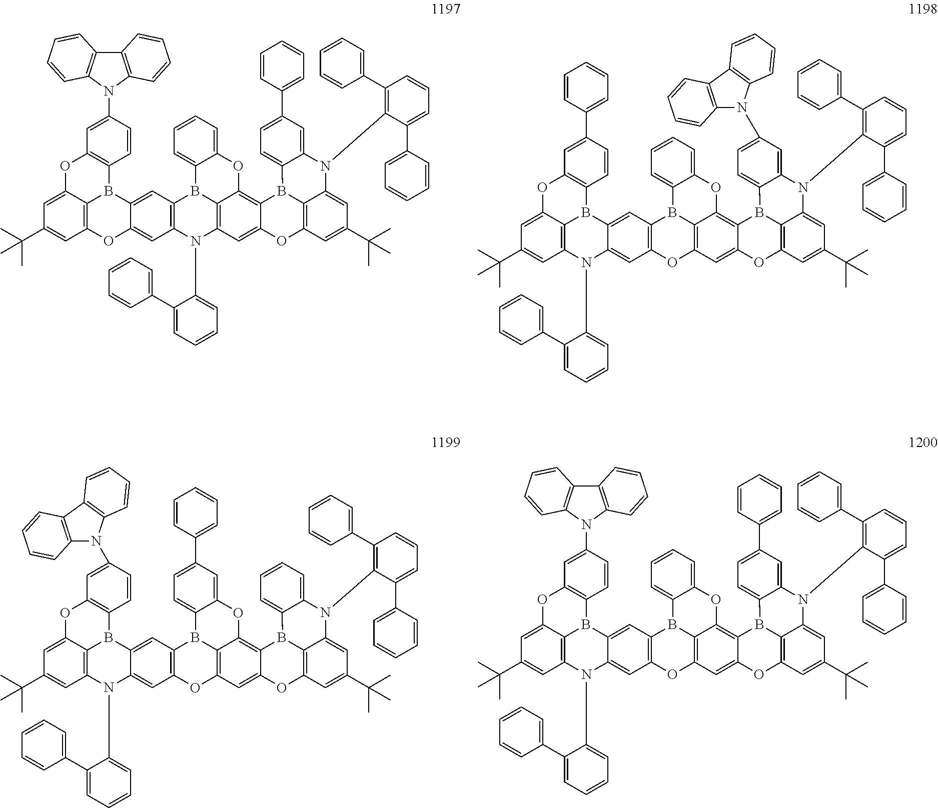 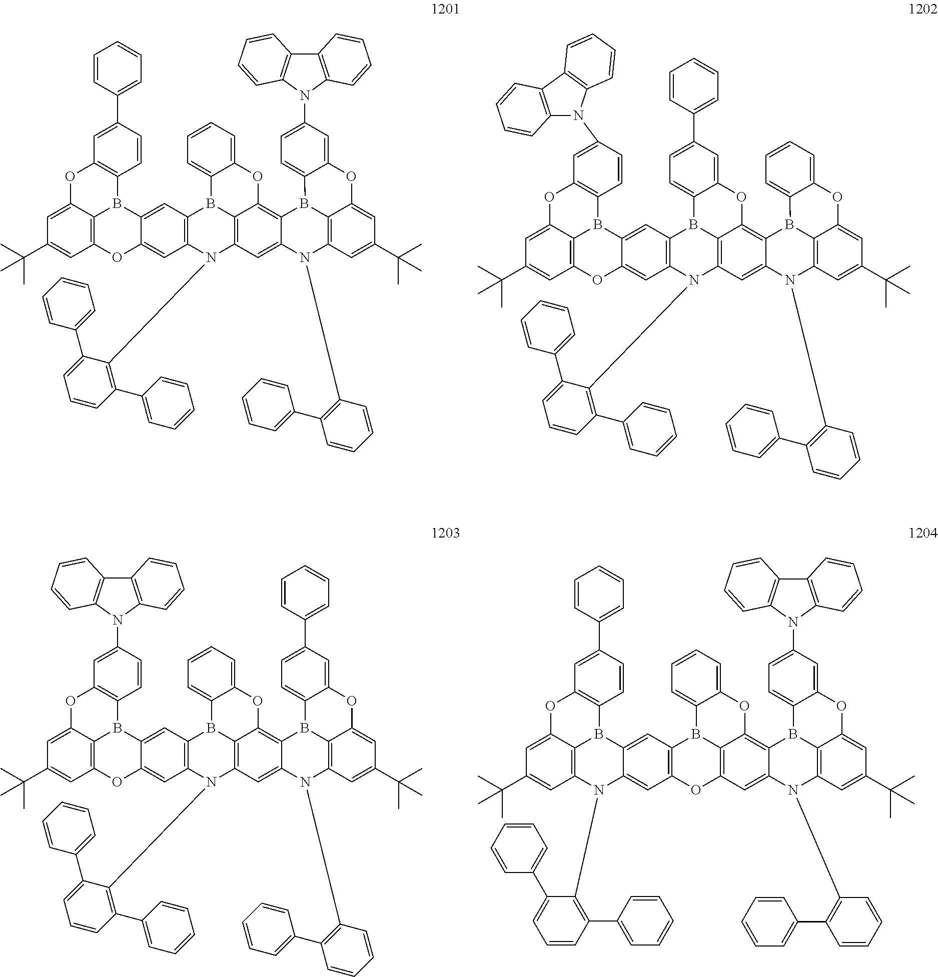 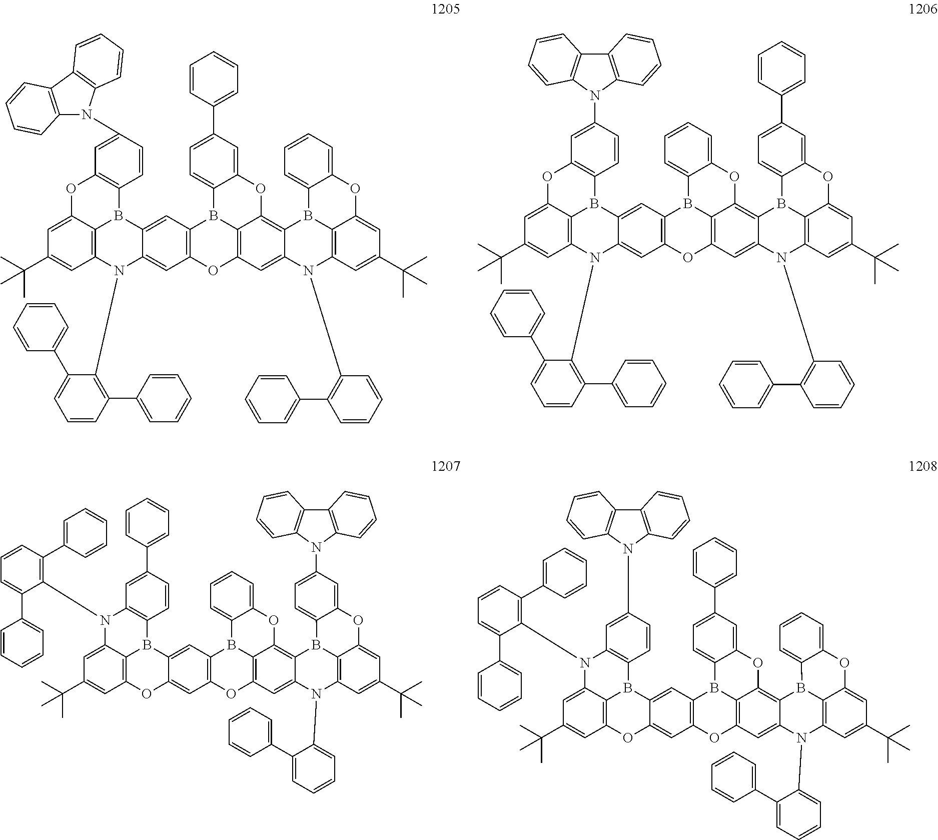 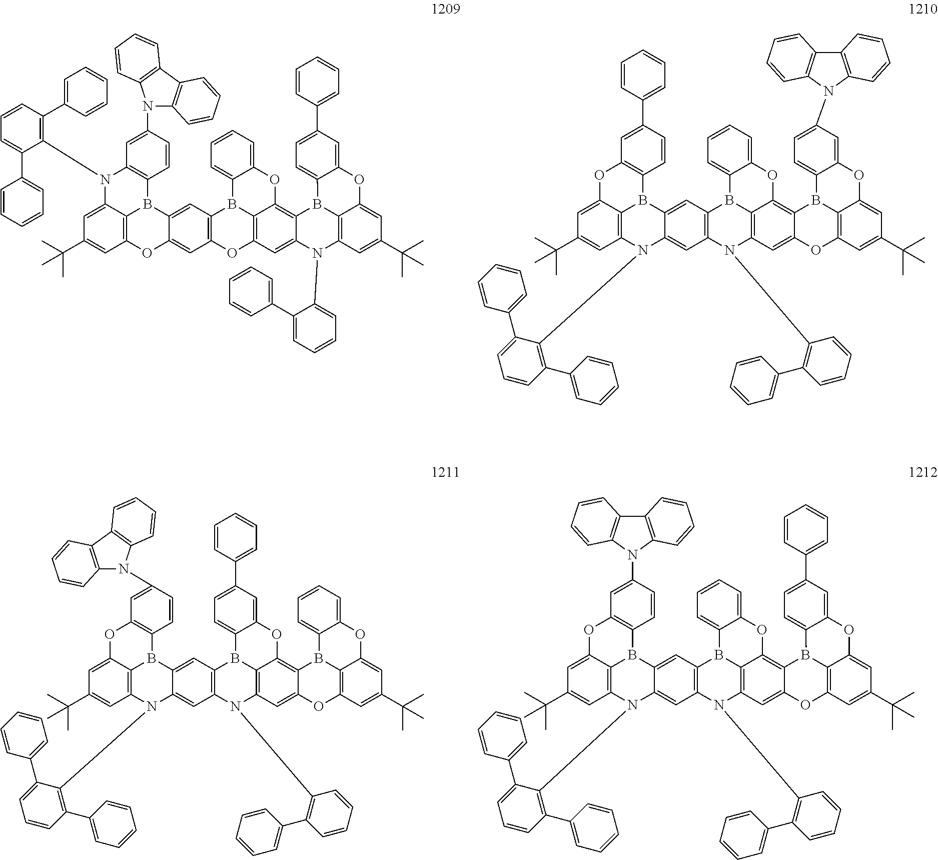 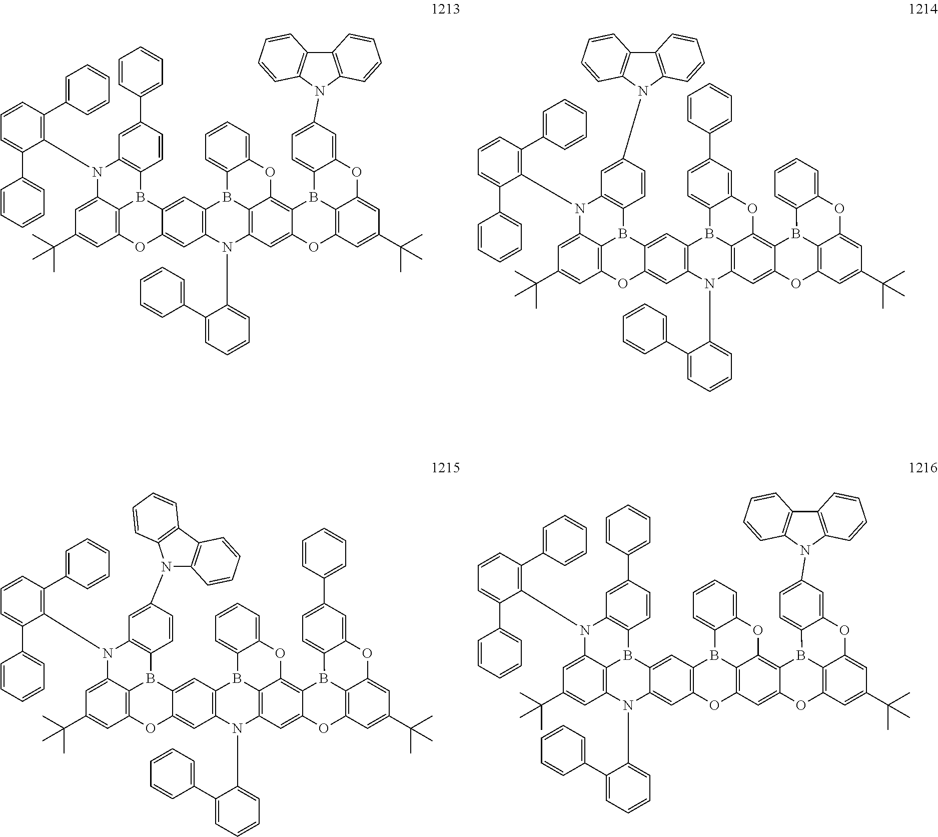 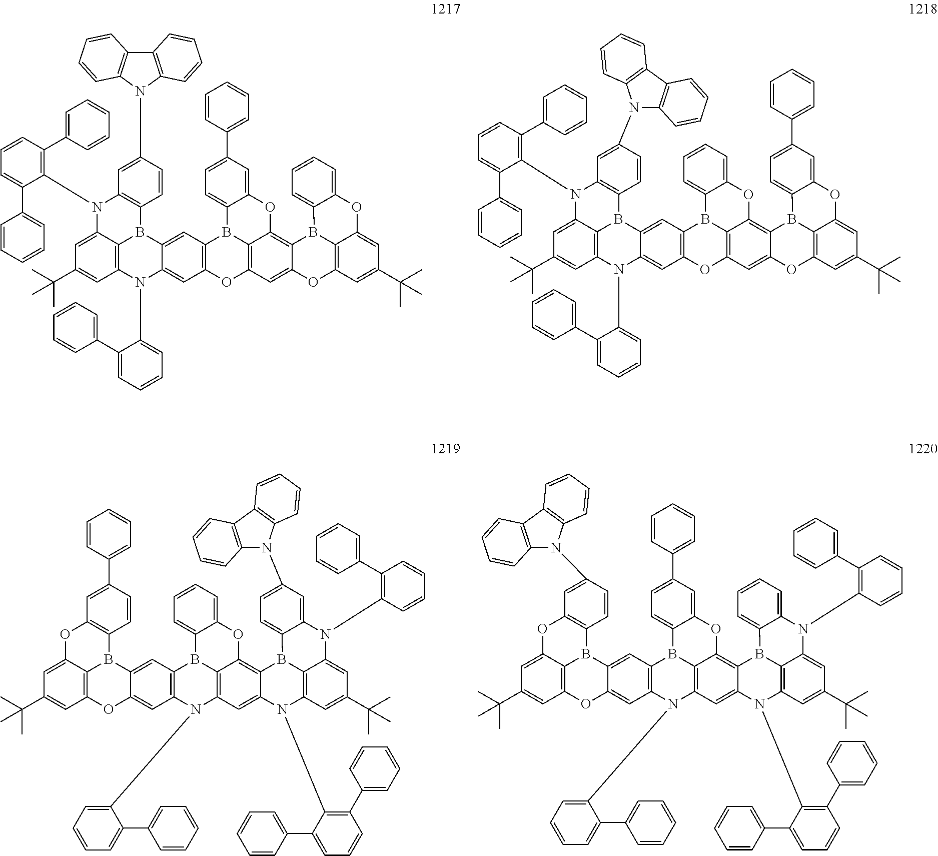 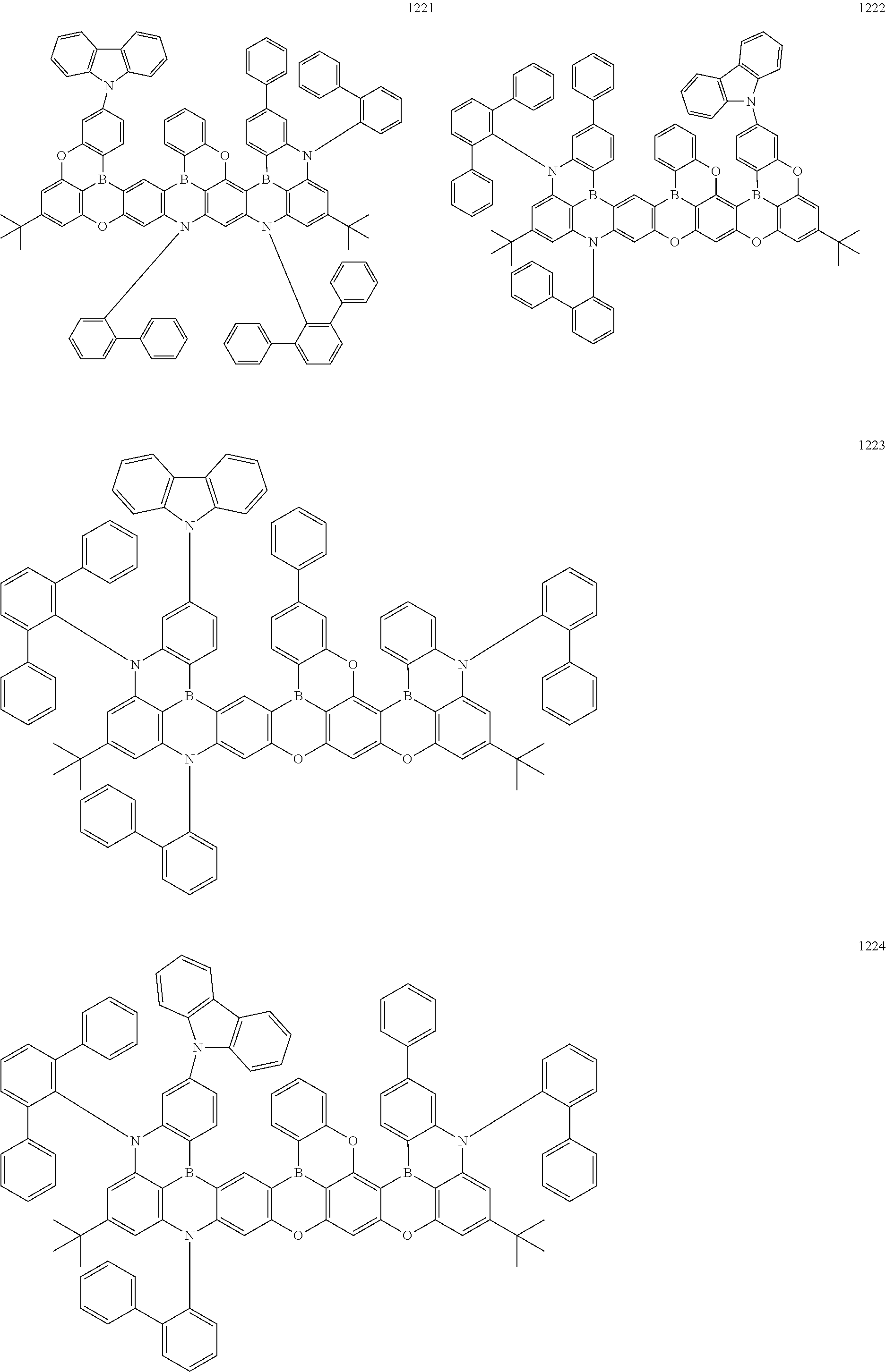 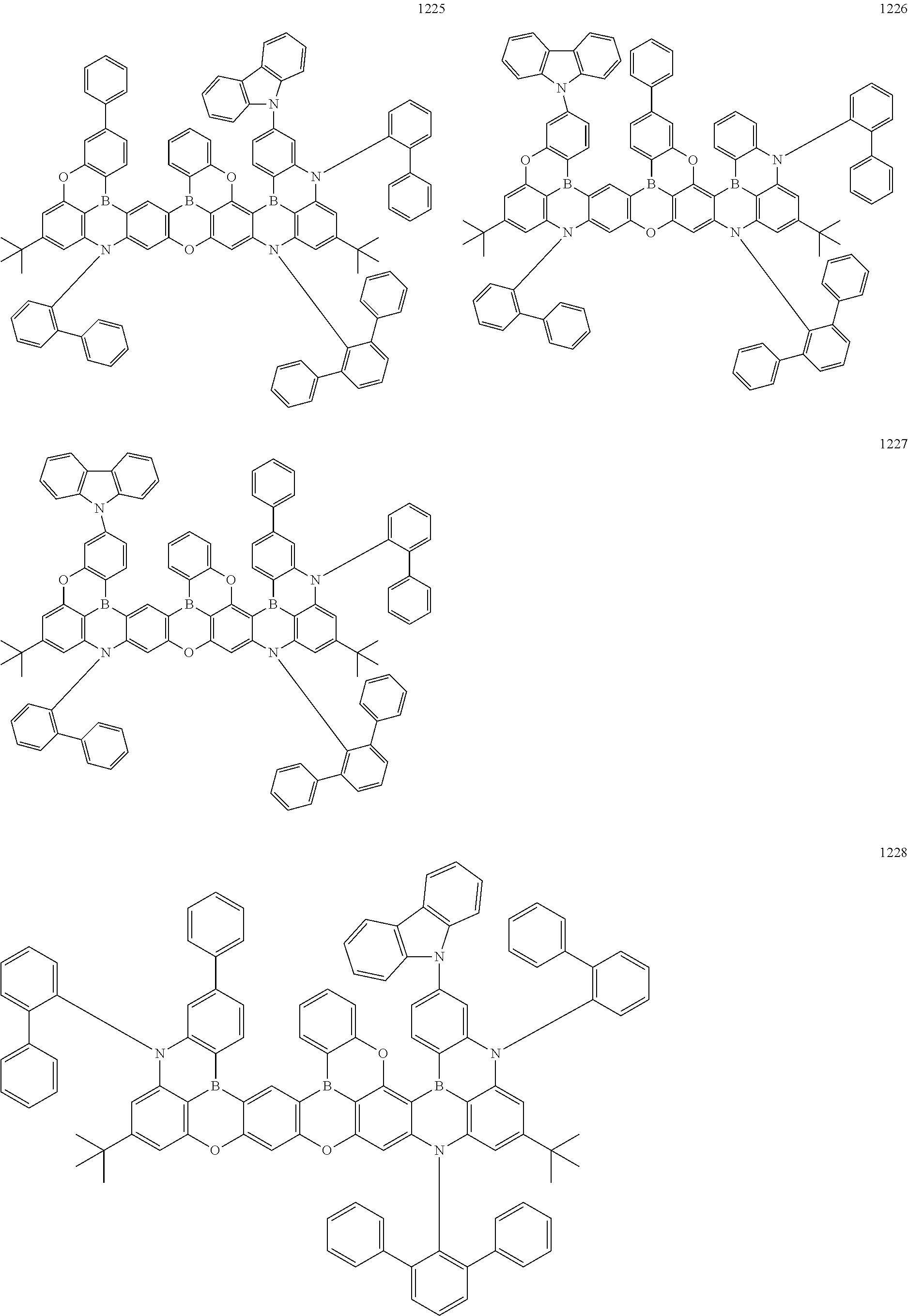 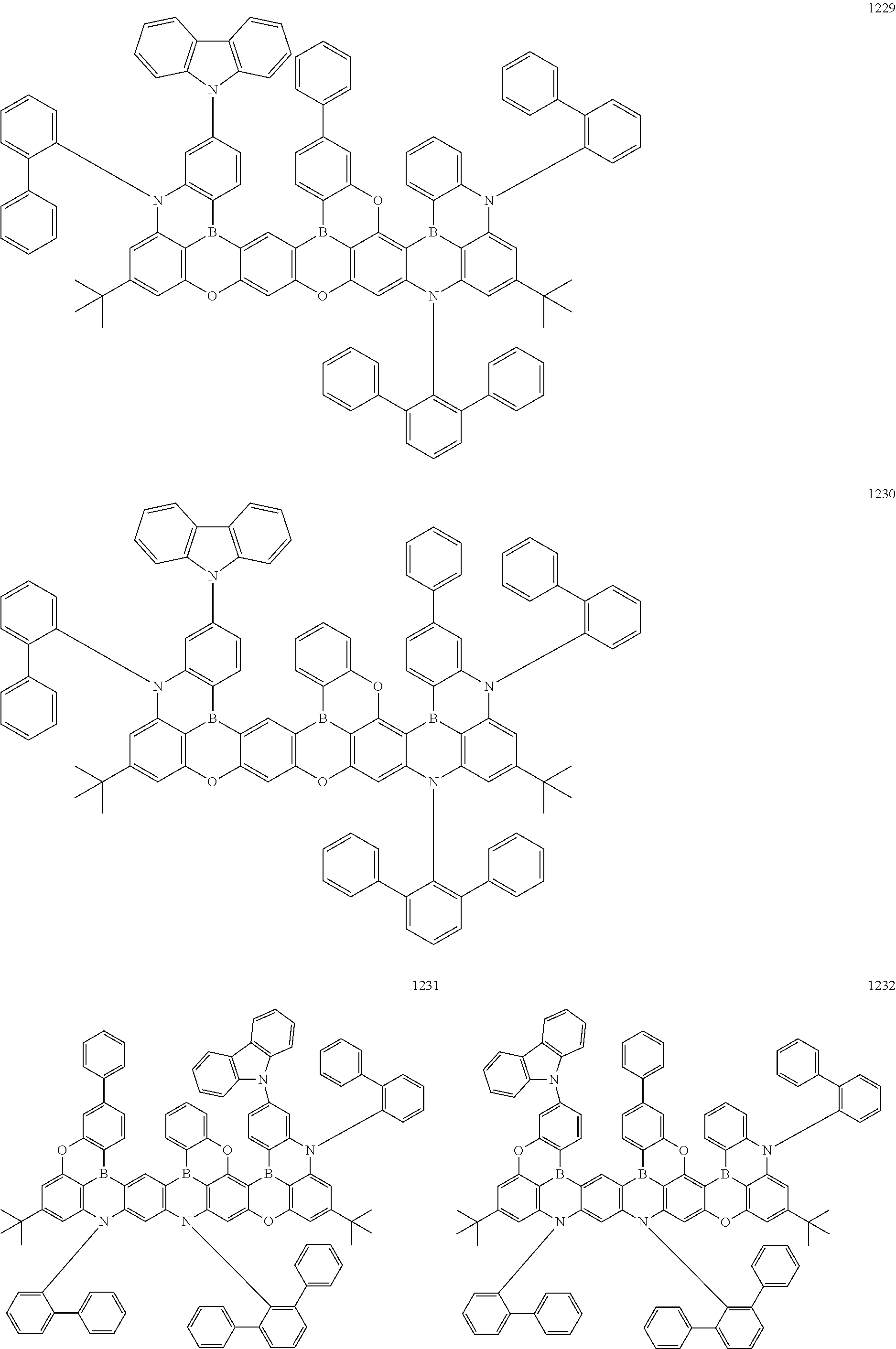 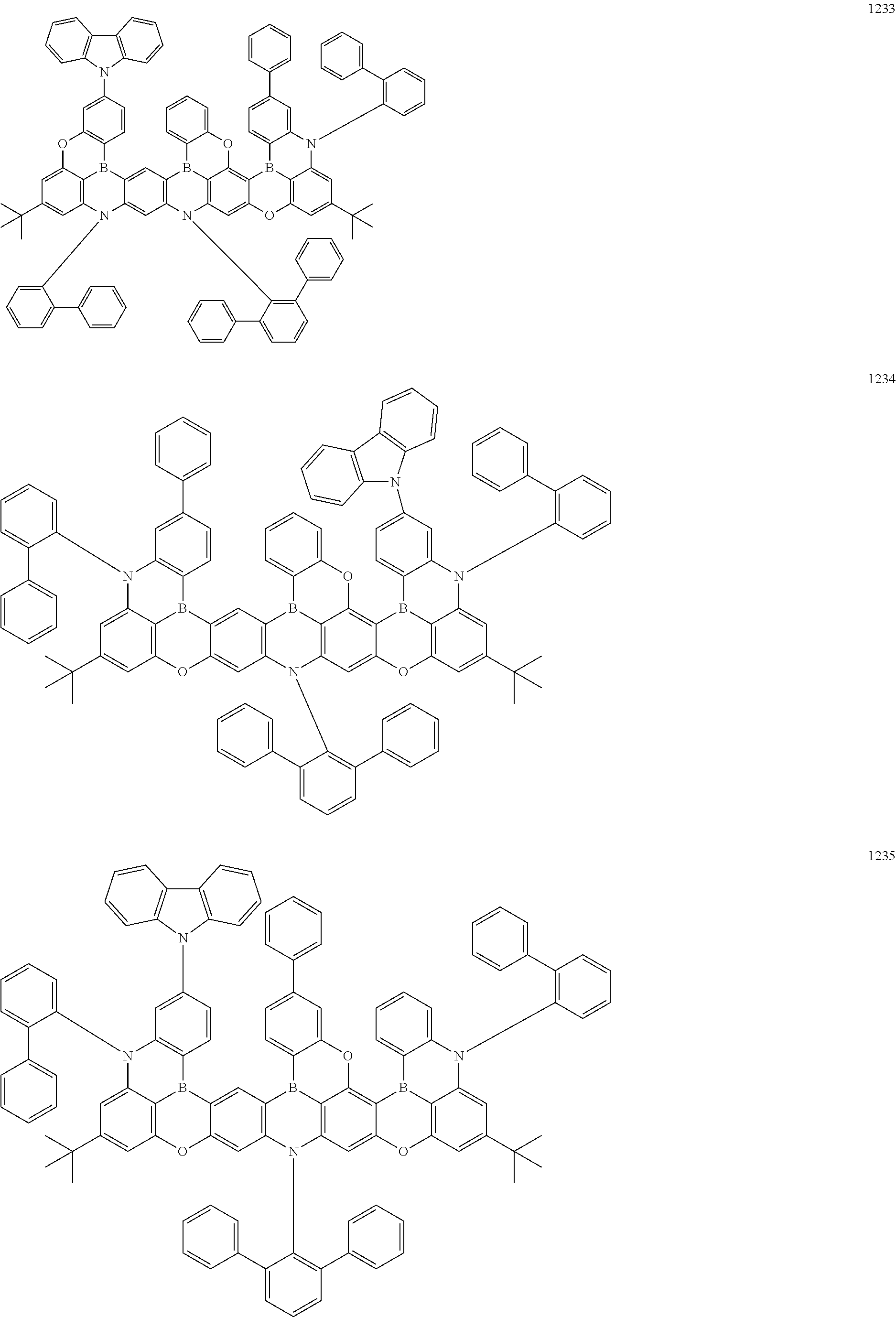 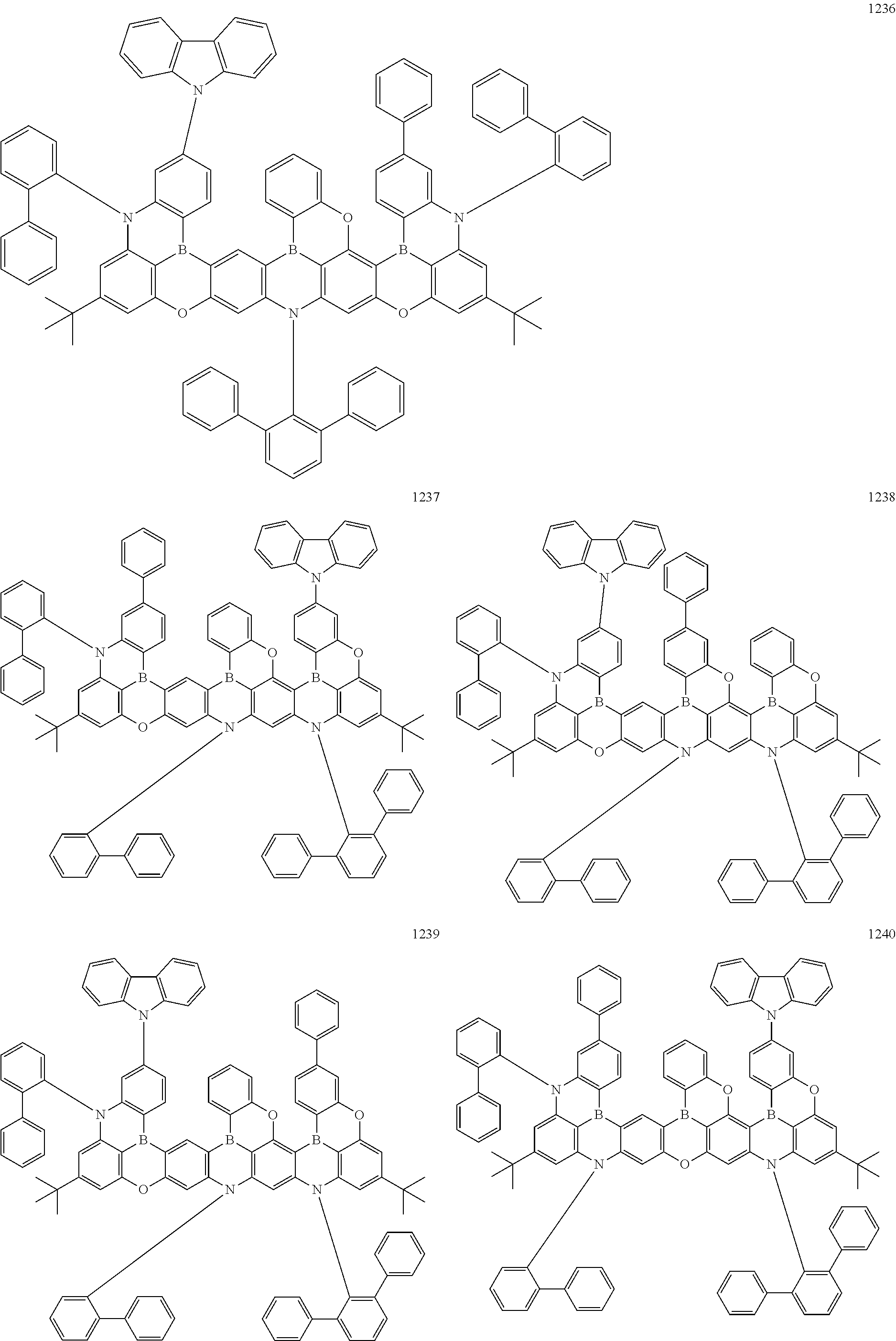 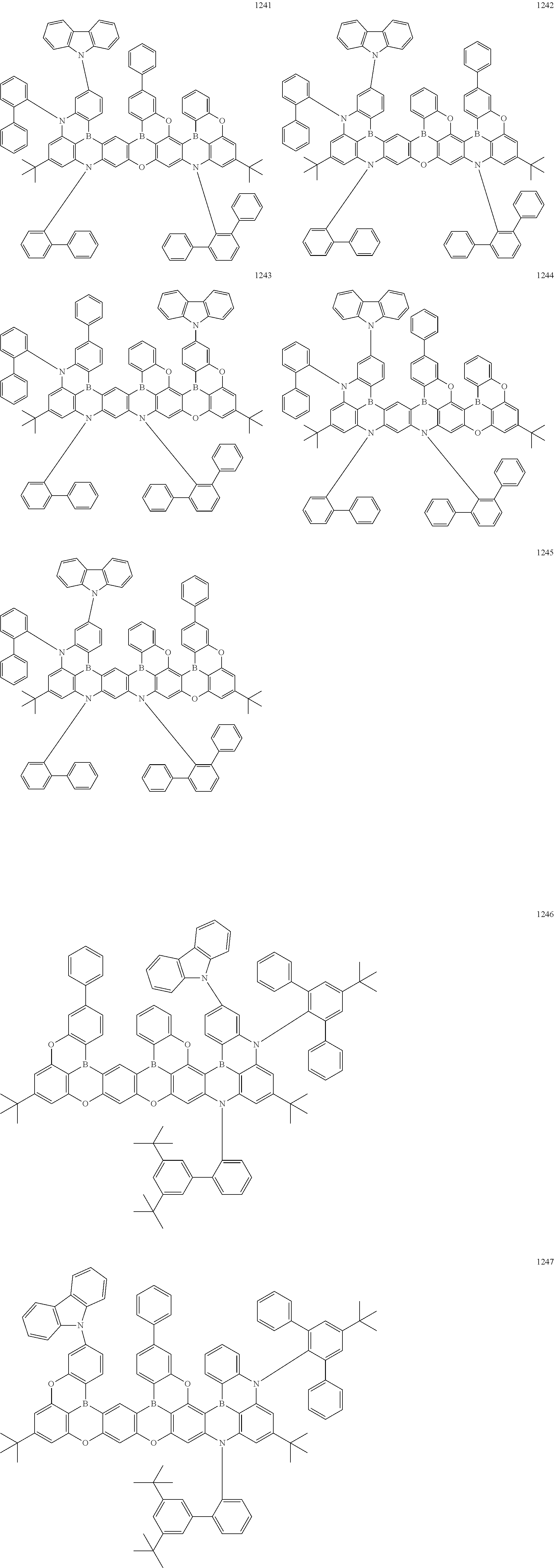 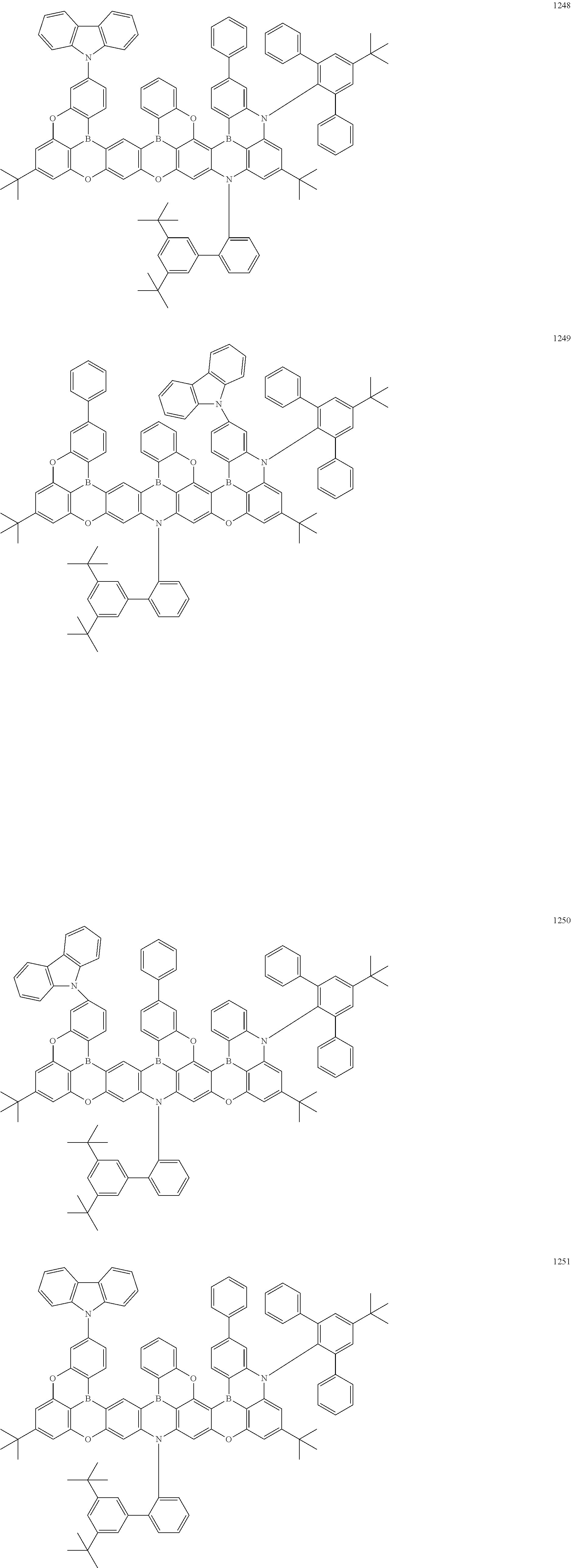 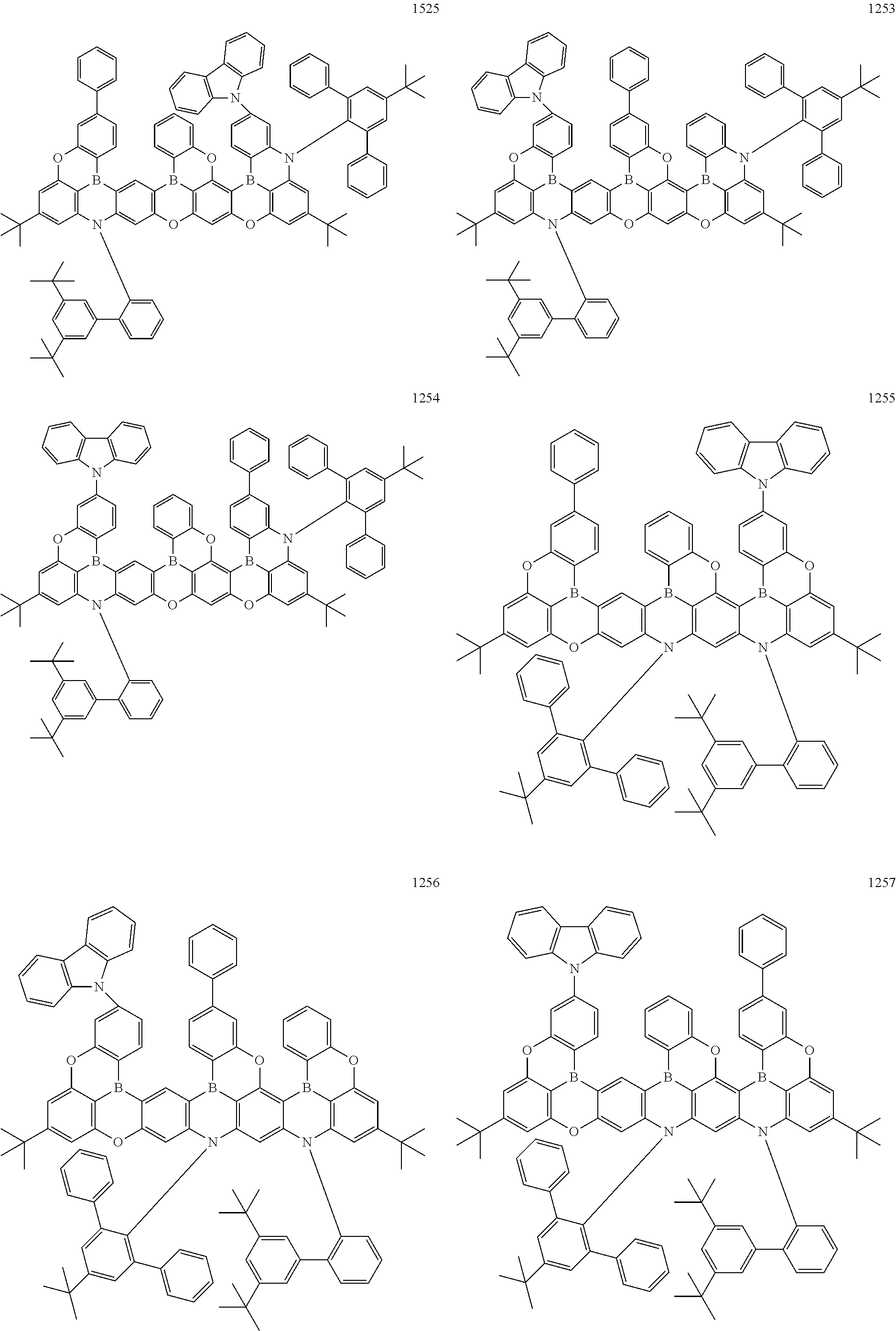 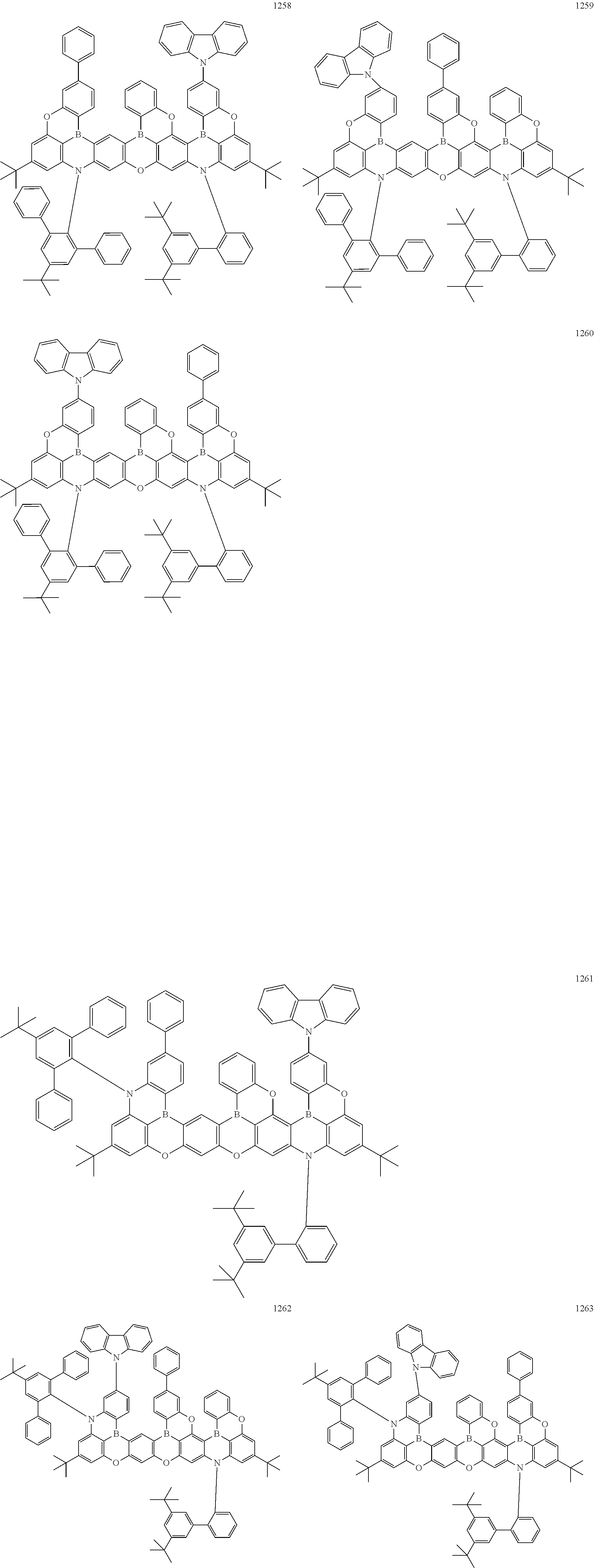 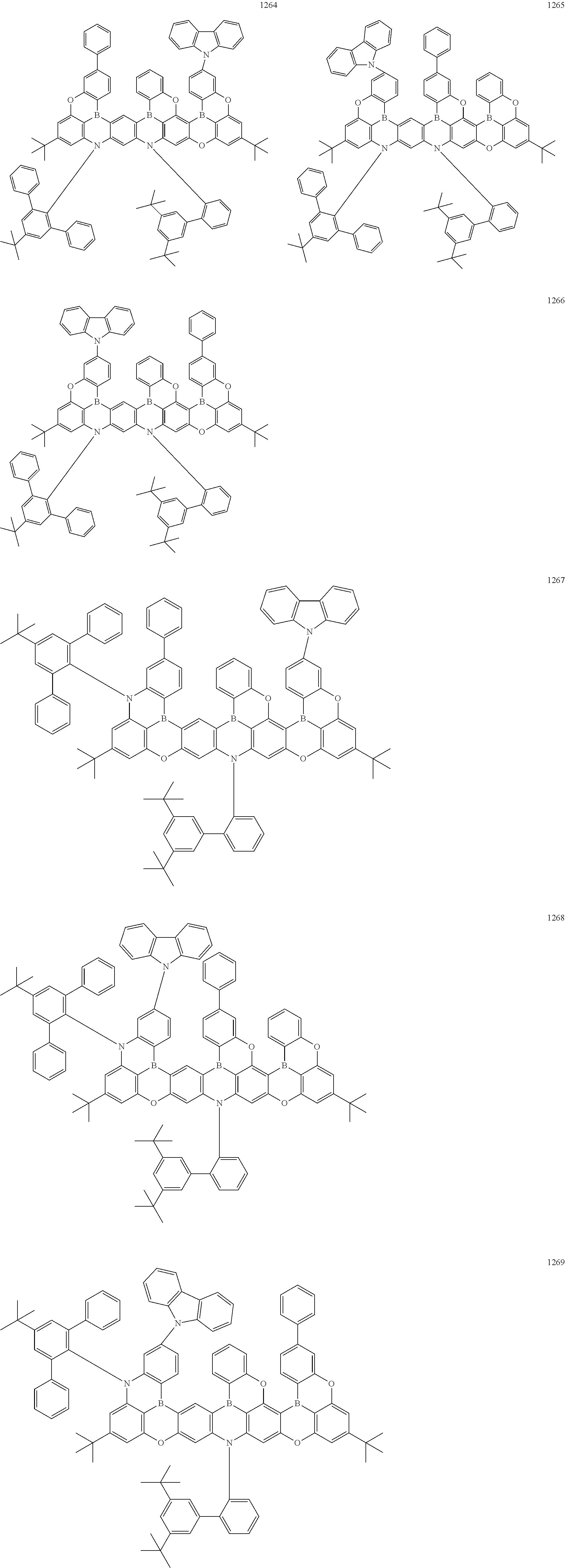 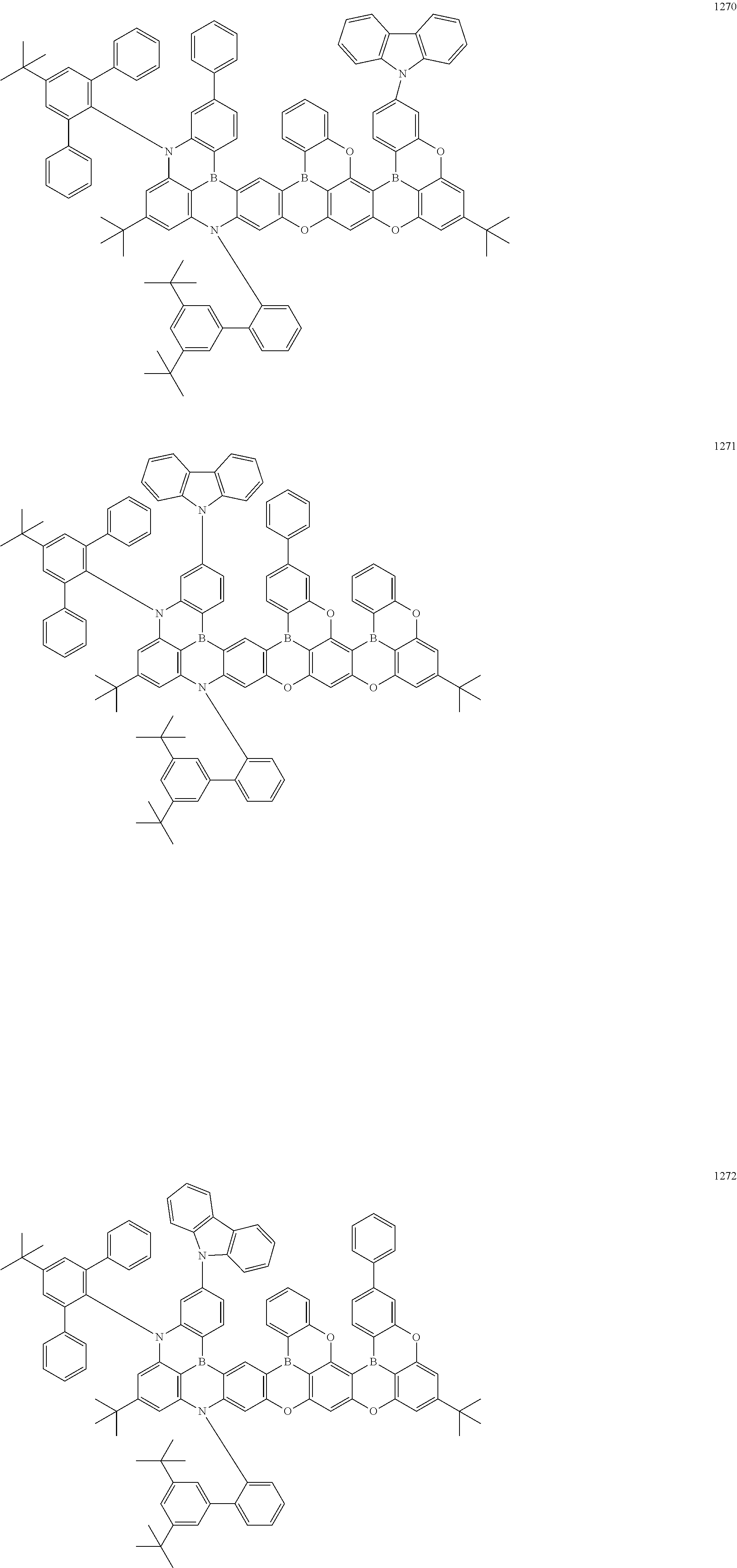 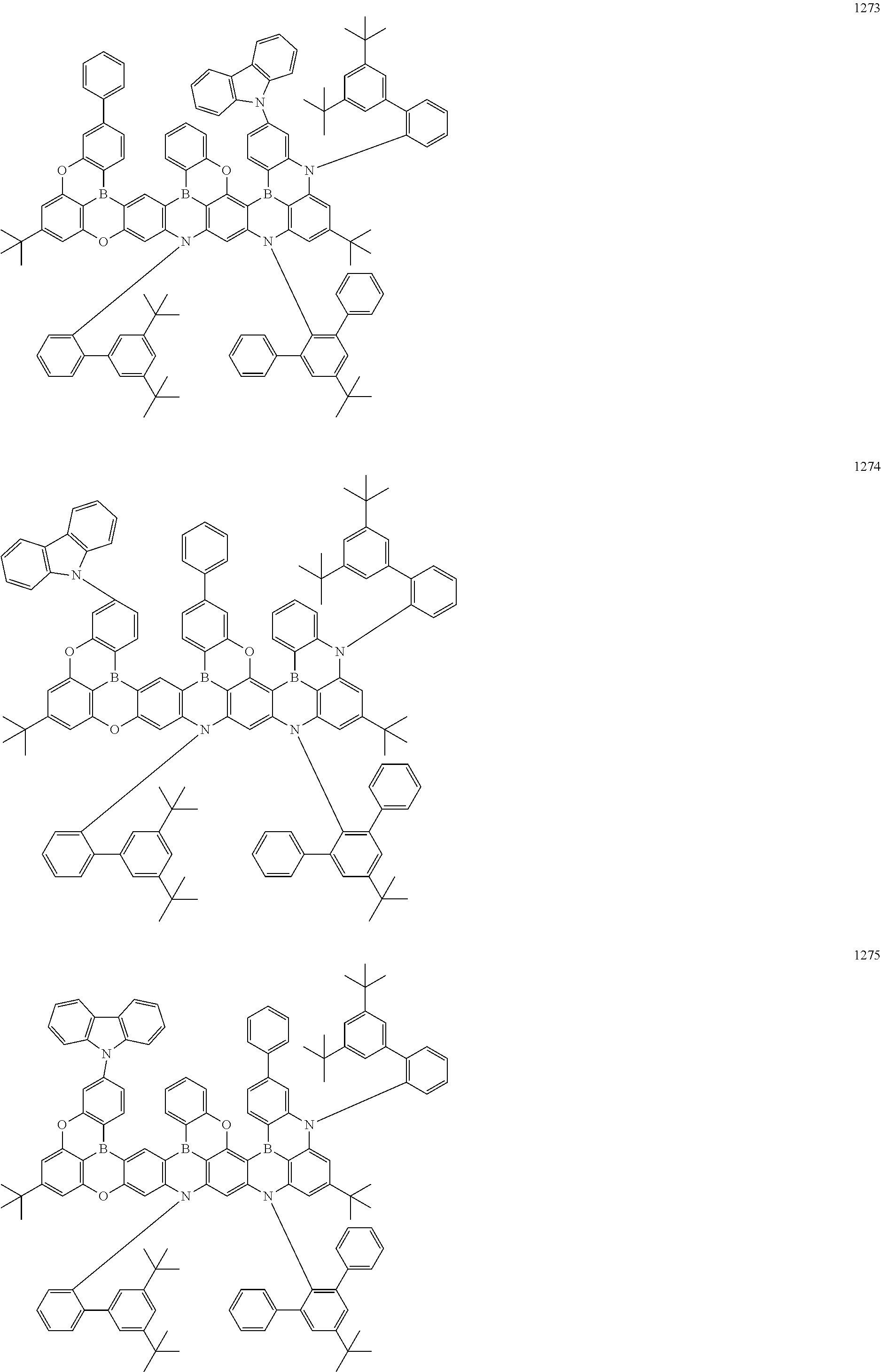 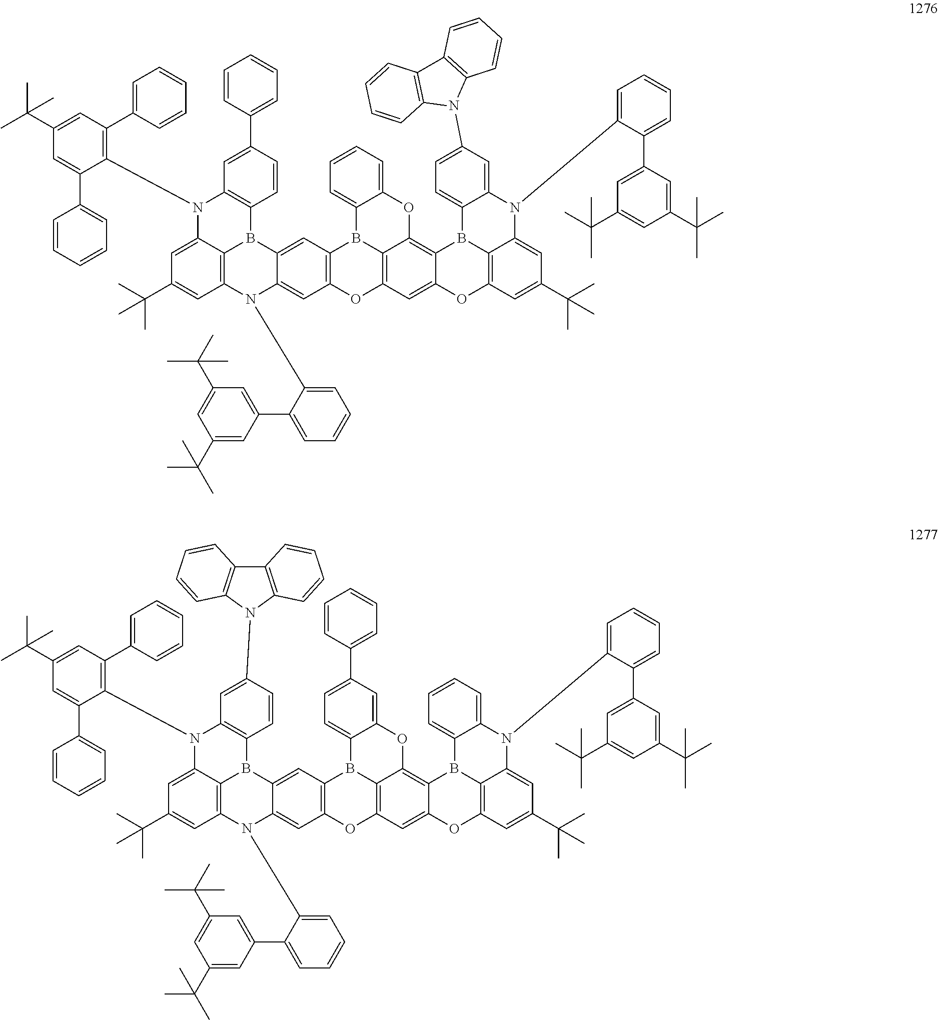 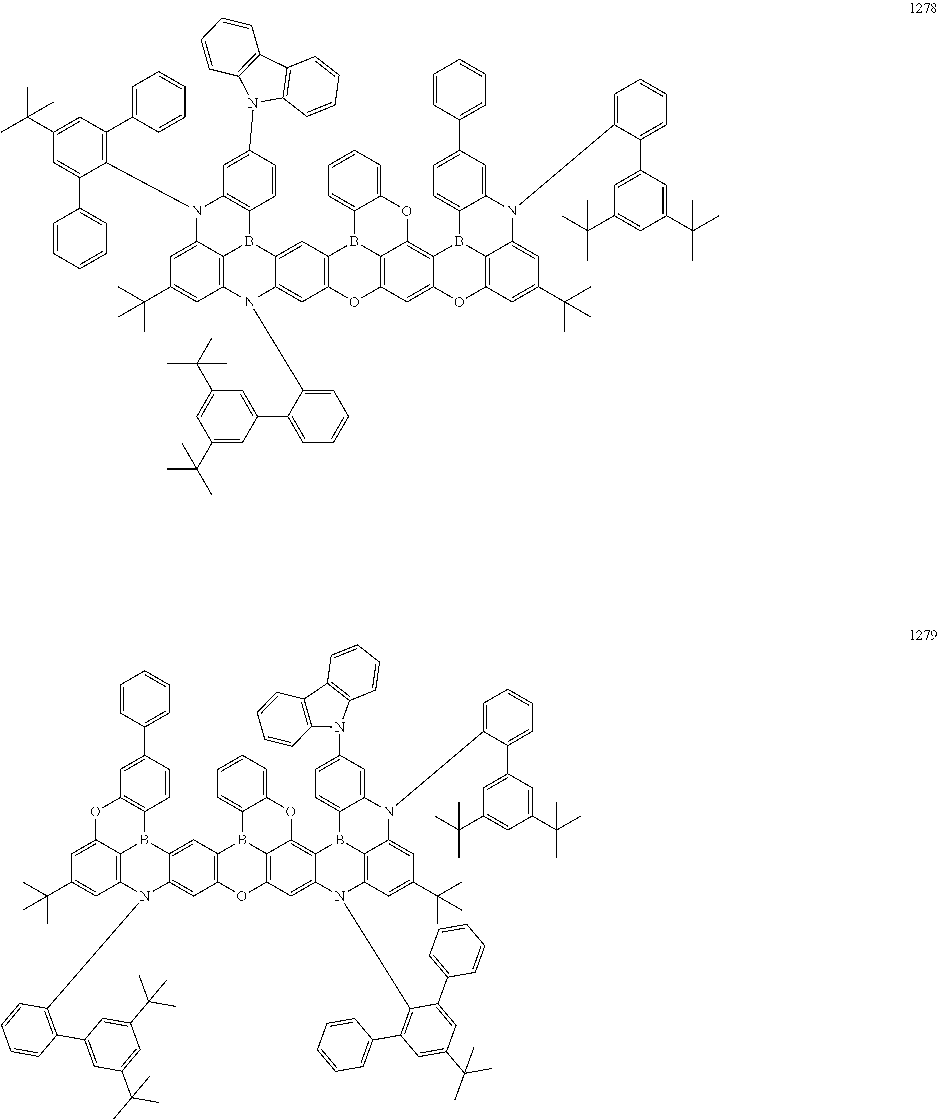 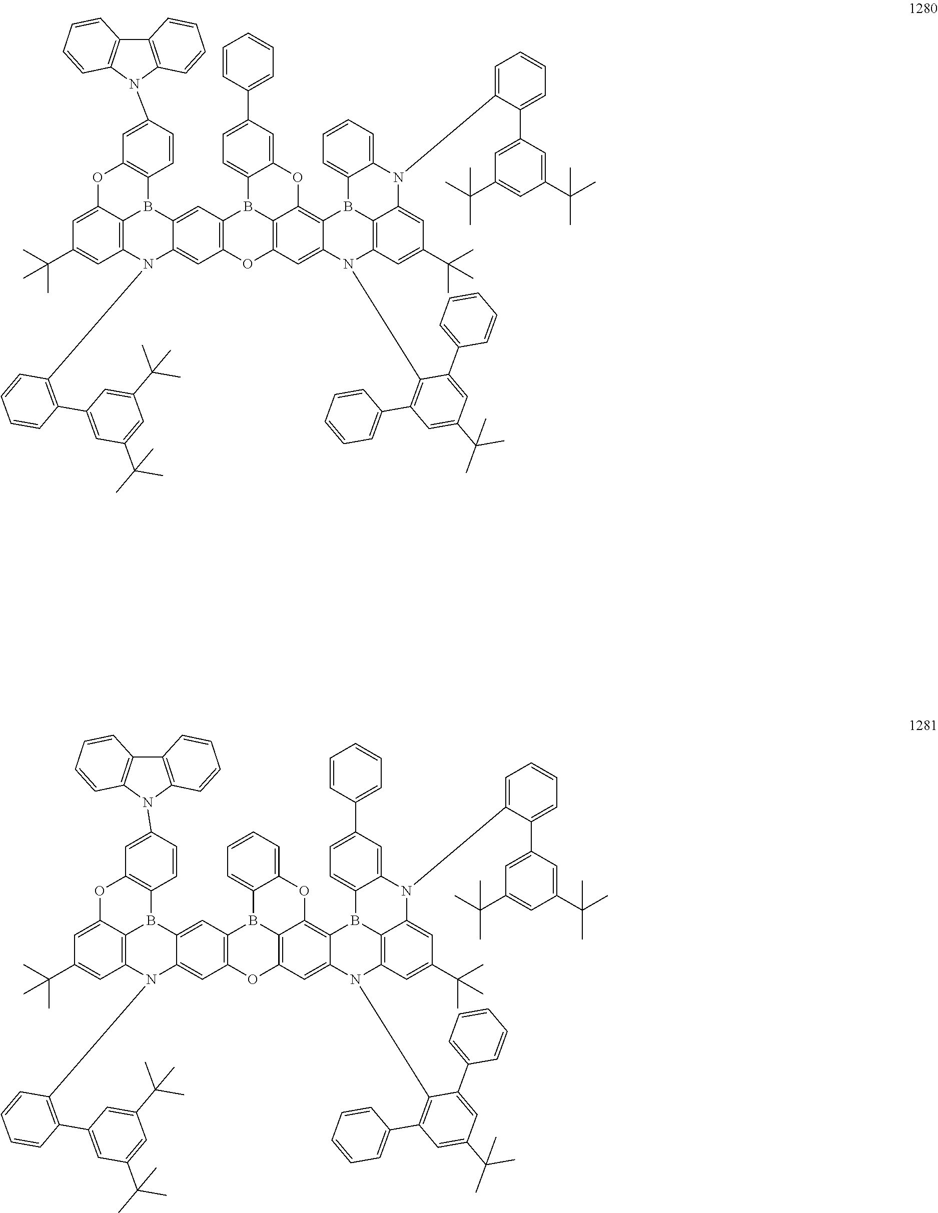 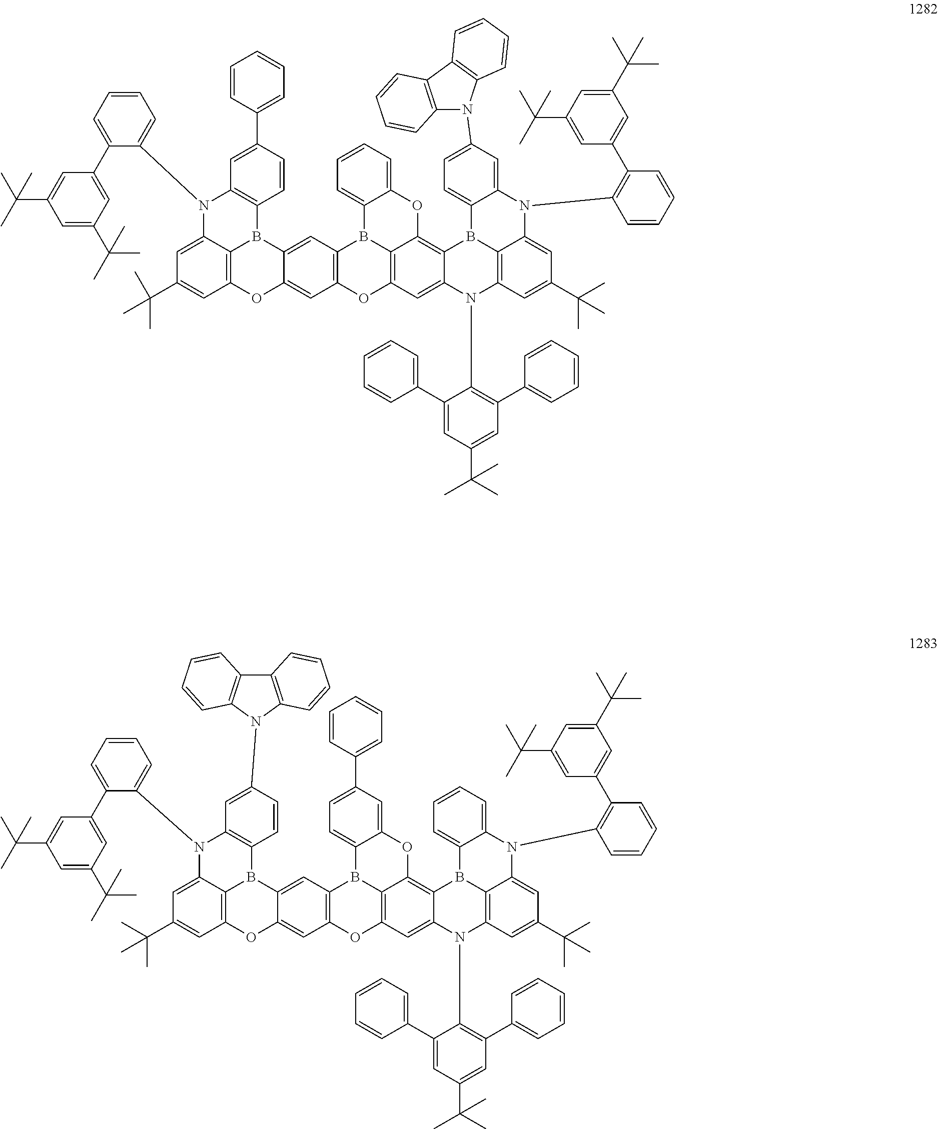 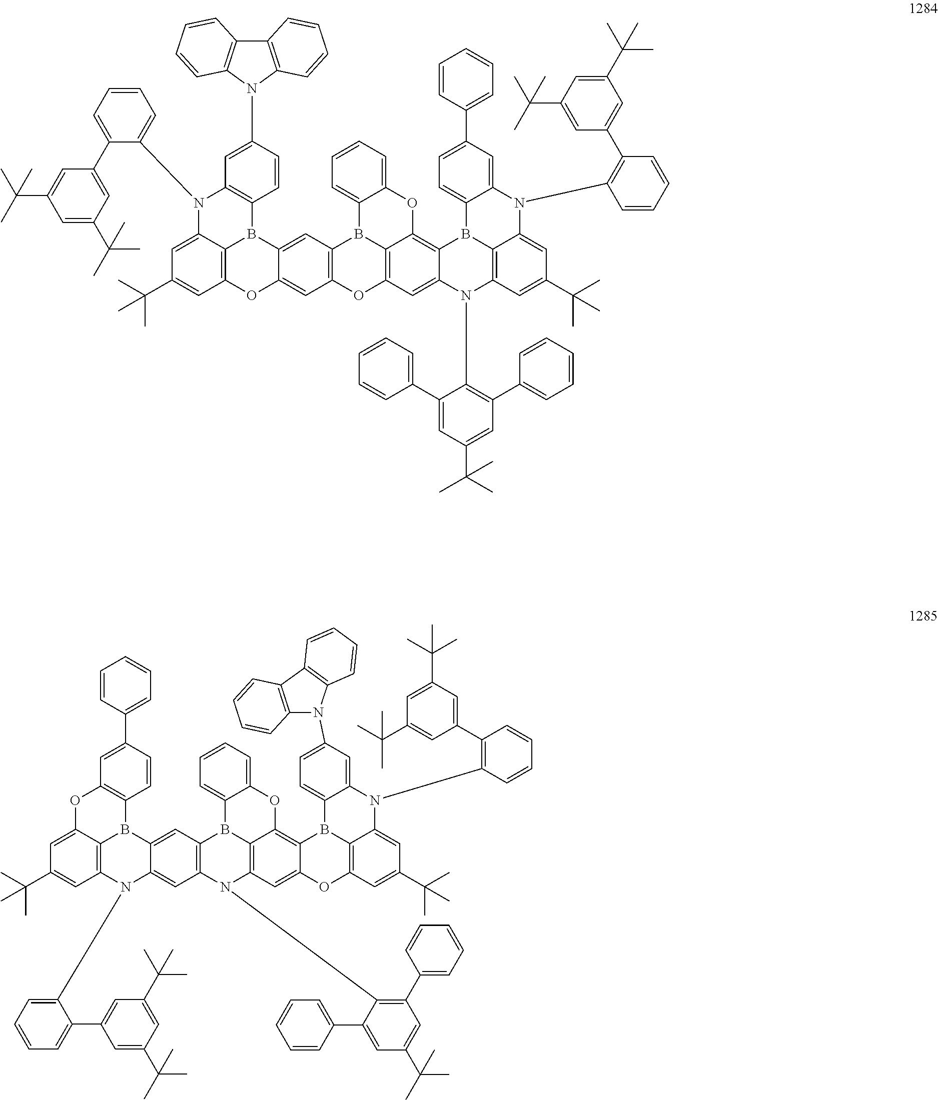 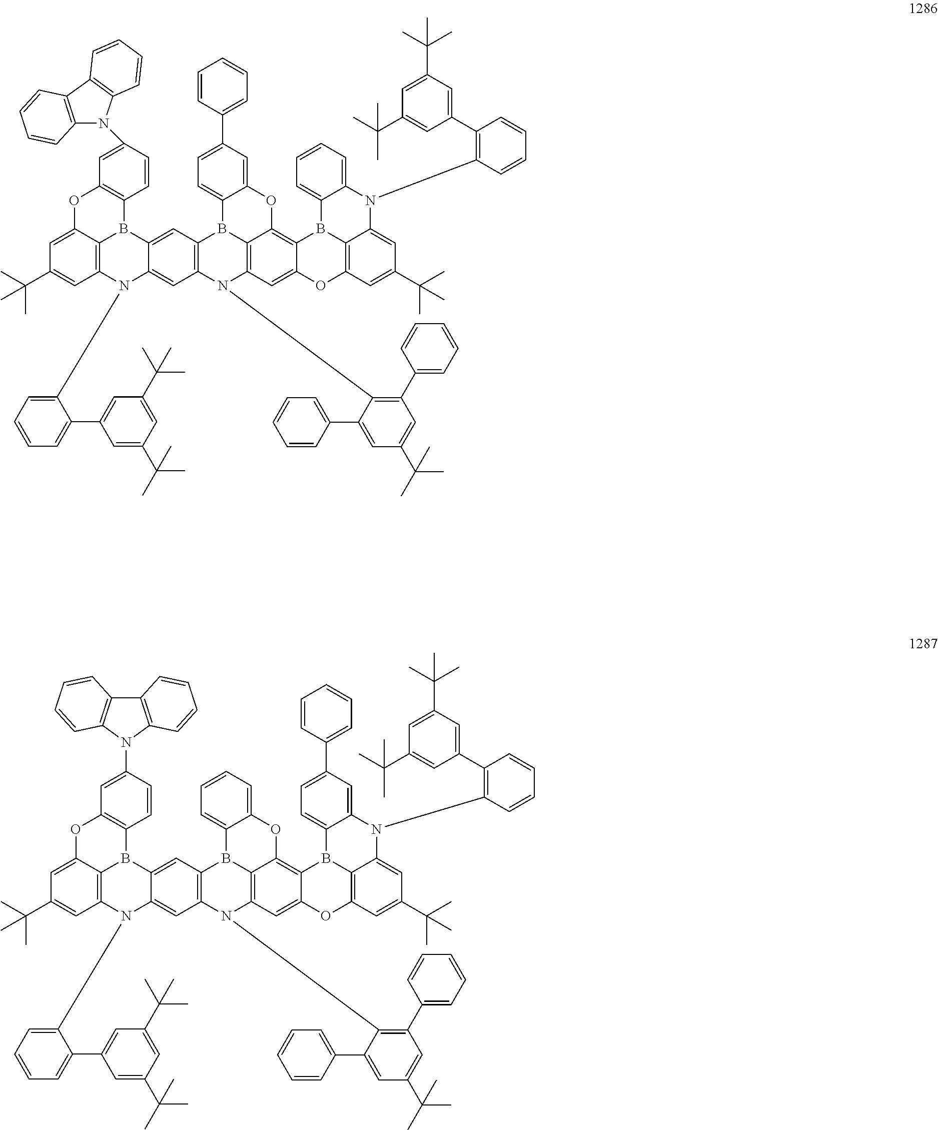 [SMILES: CC(C)(C)c1cc(-c2ccccc2N2c3cc4c(cc3B3c5ccc(-n6c7ccccc7c7ccccc76)cc5Oc5cc(C(C)(C)C)cc2c53)B2c3ccc(-c5ccccc5)cc3Oc3c5c(cc(c32)N4c2c(-c3ccccc3)cc(C(C)(C)C)cc2-c2ccccc2)Oc2cc(C(C)(C)C)cc3c2B5c2ccccc2N3c2ccccc2-c2cc(C(C)(C)C)cc(C(C)(C)C)c2)cc(C(C)(C)C)c1 ; CC(C)(C)c1cc(-c2ccccc2N2c3cc4c(cc3B3c5ccc(-n6c7ccccc7c7ccccc76)cc5Oc5cc(C(C)(C)C)cc2c53)B2c3ccccc3Oc3c5c(cc(c32)N4c2c(-c3ccccc3)cc(C(C)(C)C)cc2-c2ccccc2)Oc2cc(C(C)(C)C)cc3c2B5c2ccc(-c4ccccc4)cc2N3c2ccccc2-c2cc(C(C)(C)C)cc(C(C)(C)C)c2)cc(C(C)(C)C)c1] 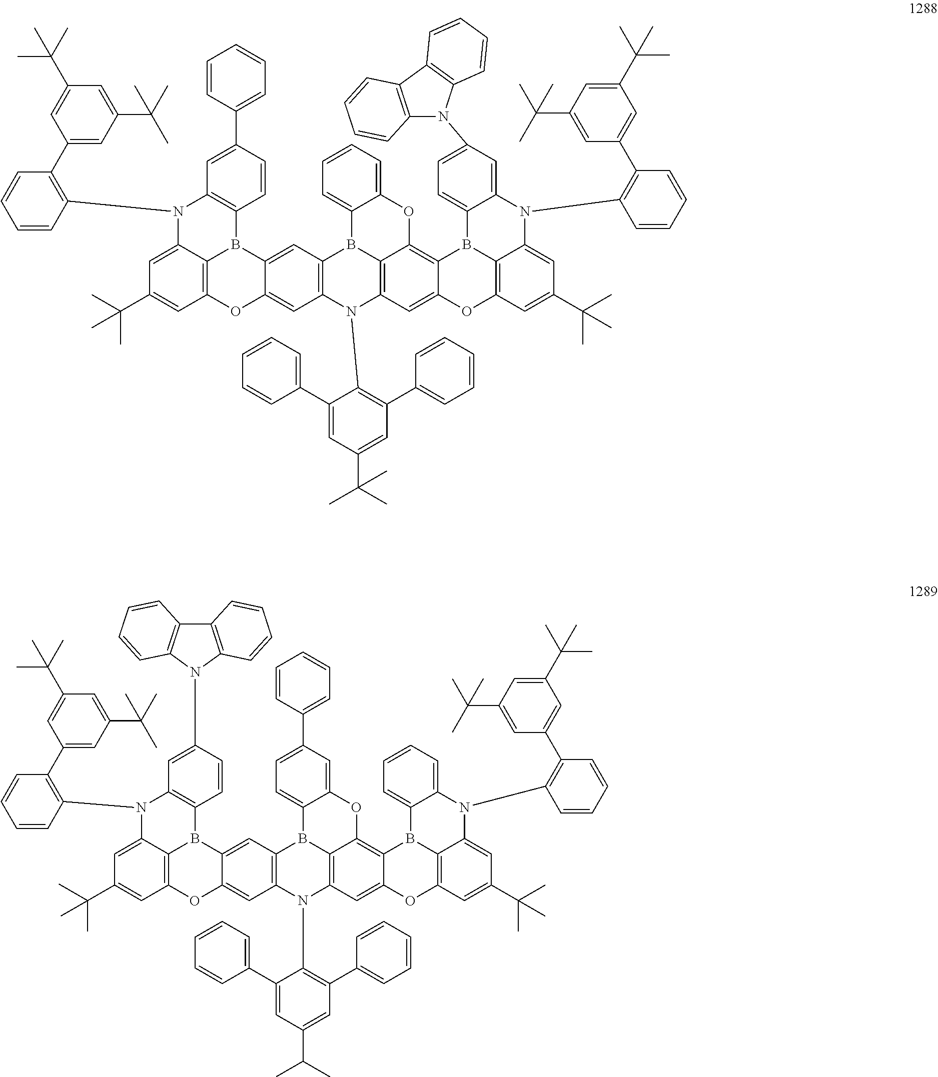 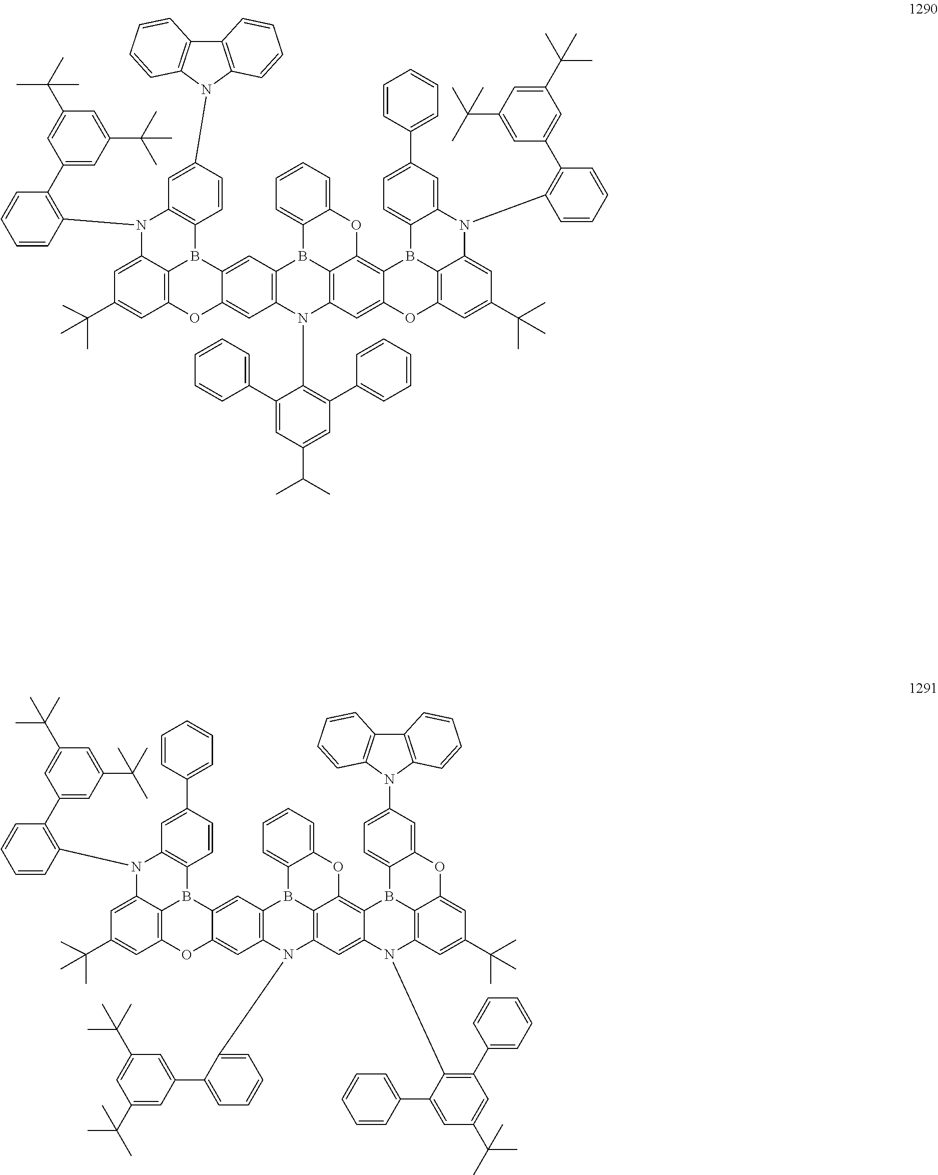 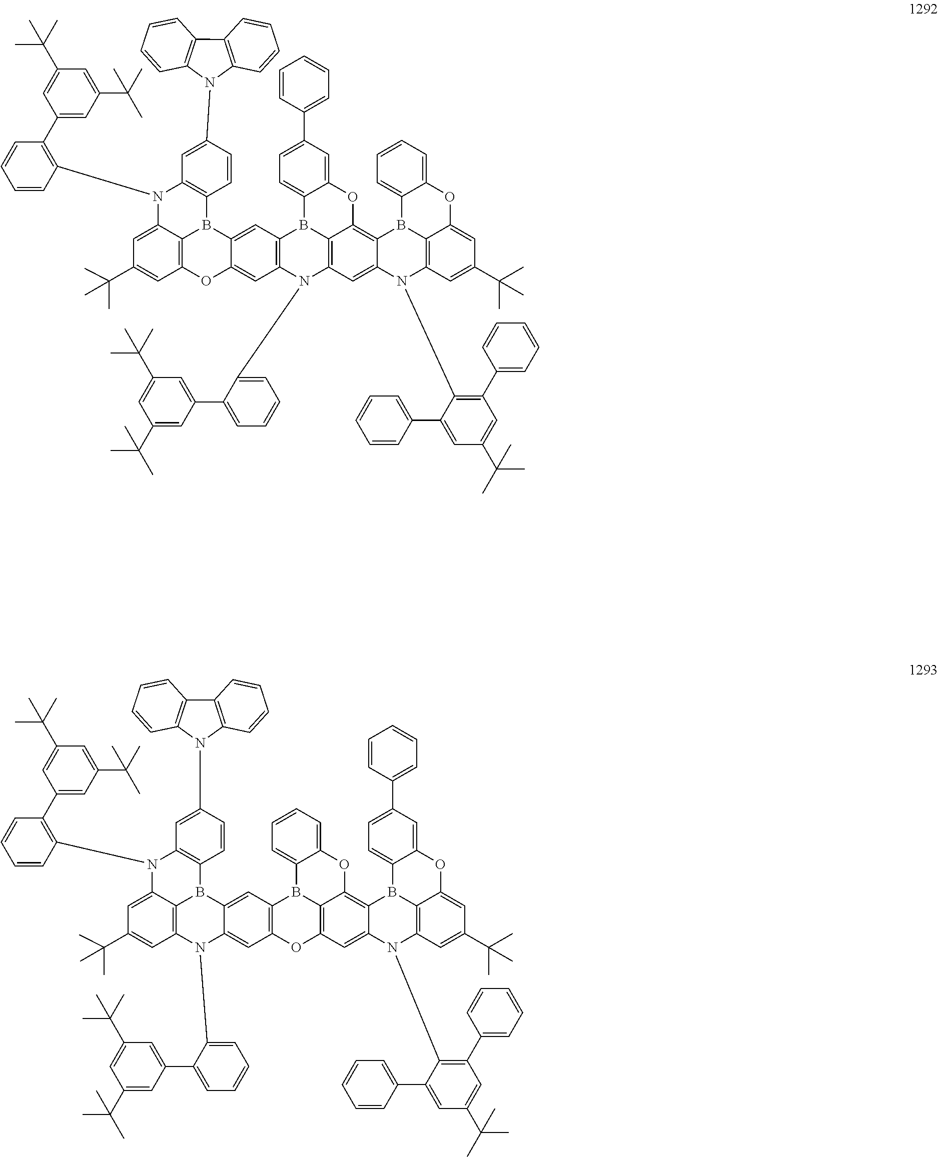 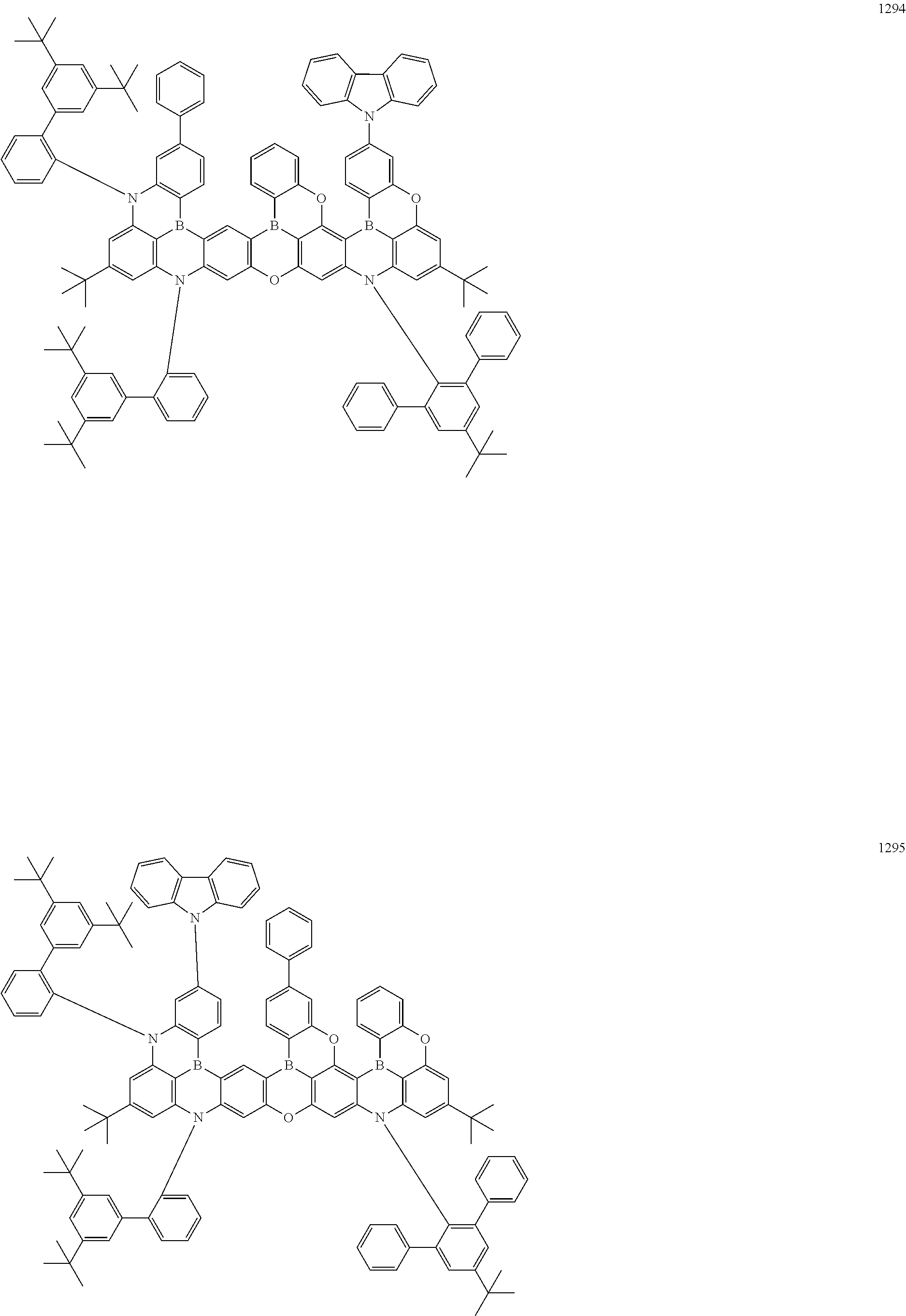 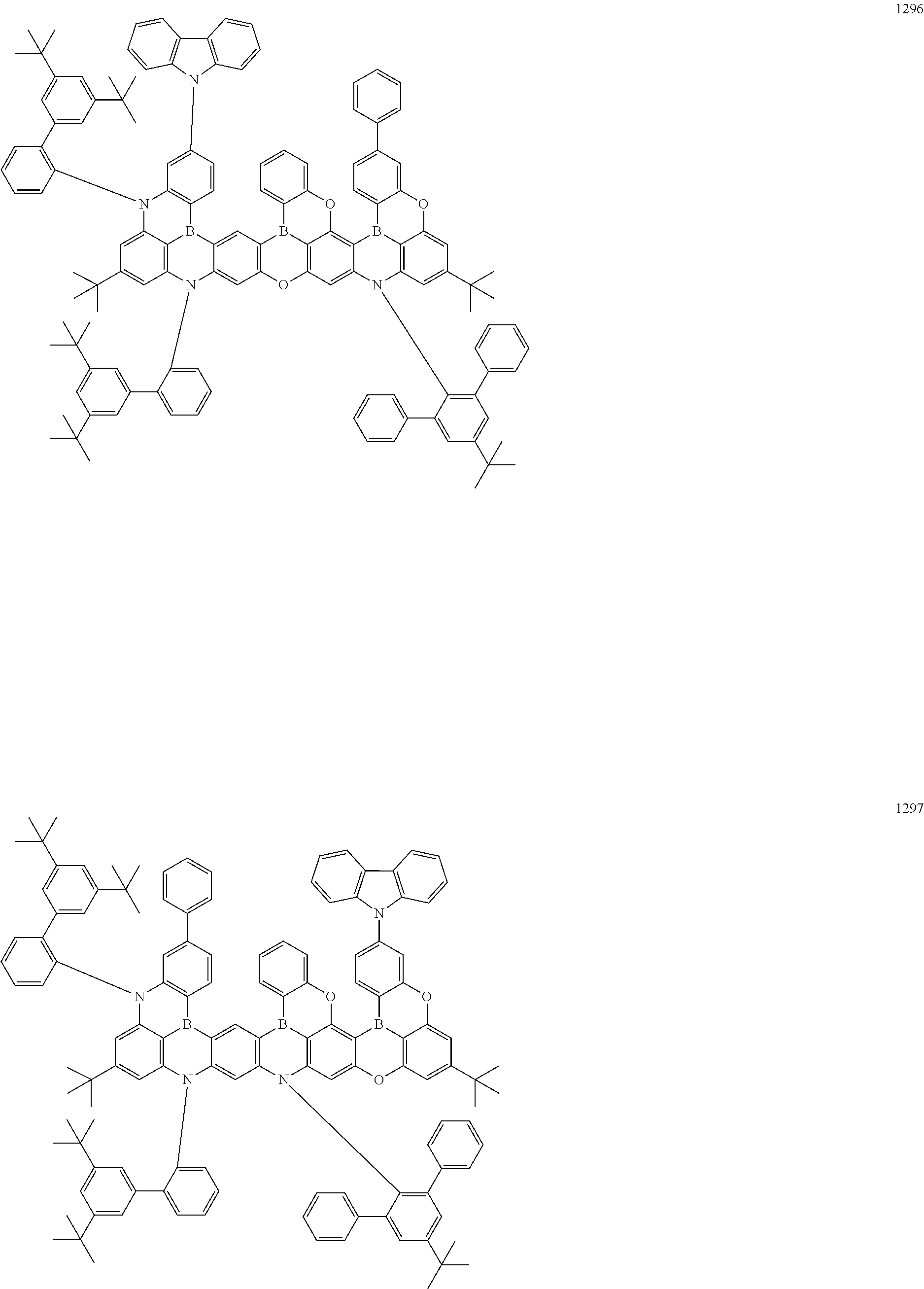 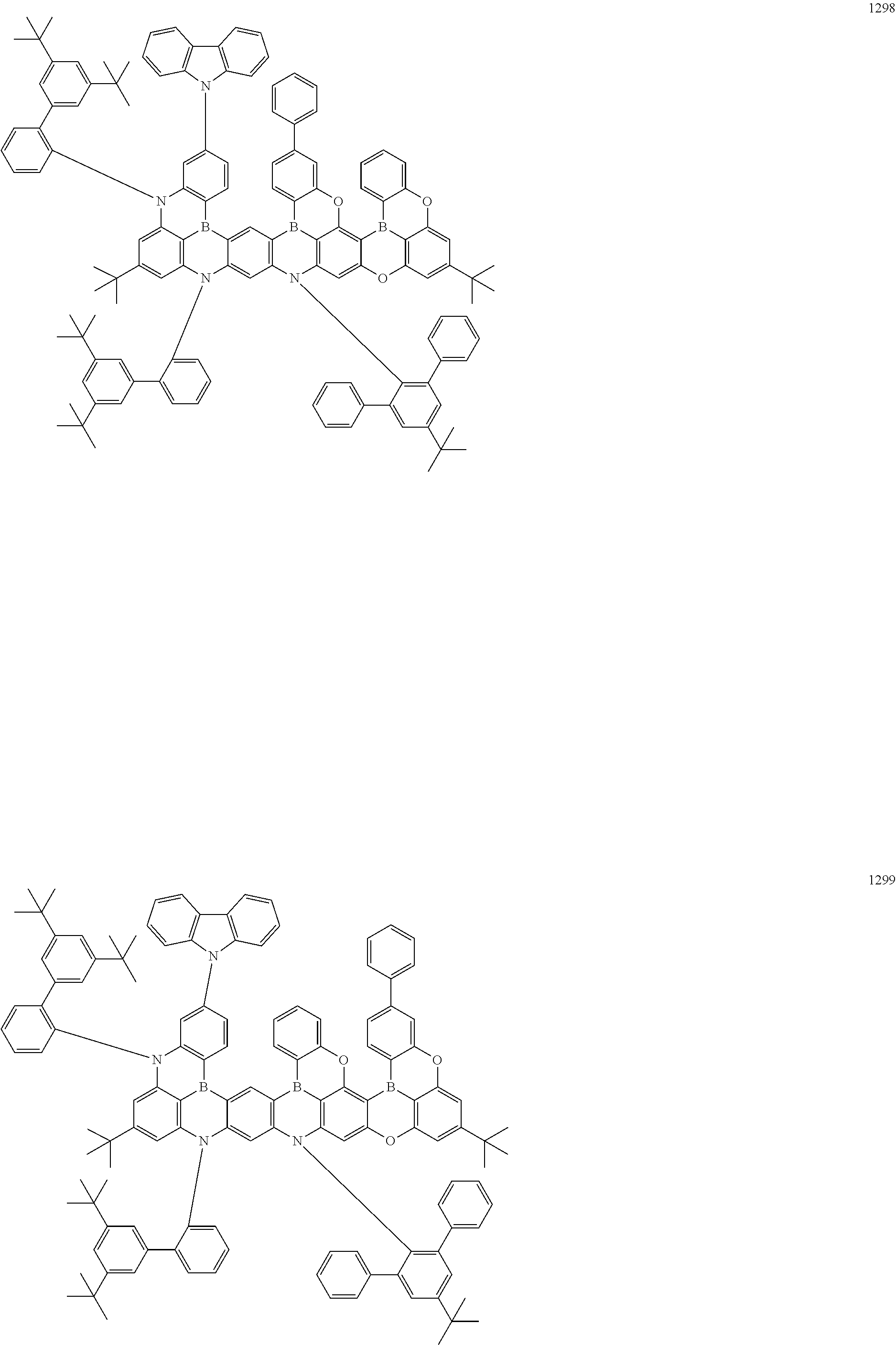 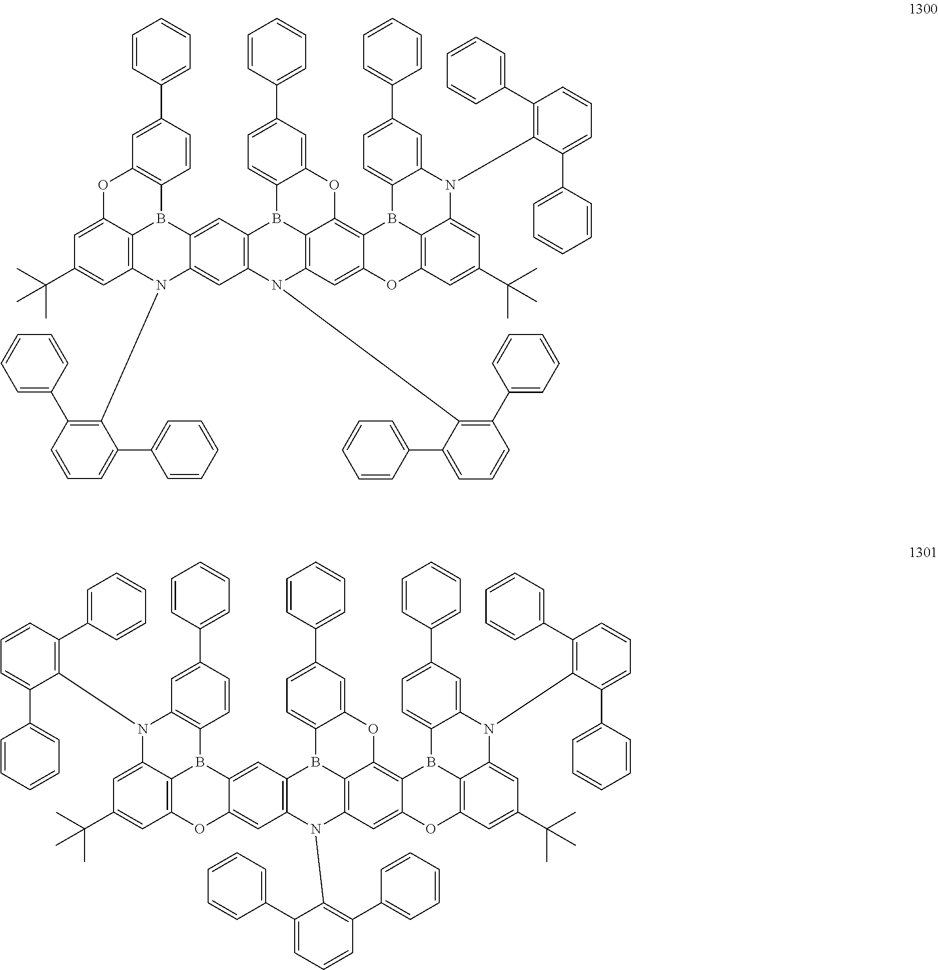 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3N(c3c(-c4ccccc4)cccc3-c3ccccc3)c3cc(C(C)(C)C)cc(c31)O2] 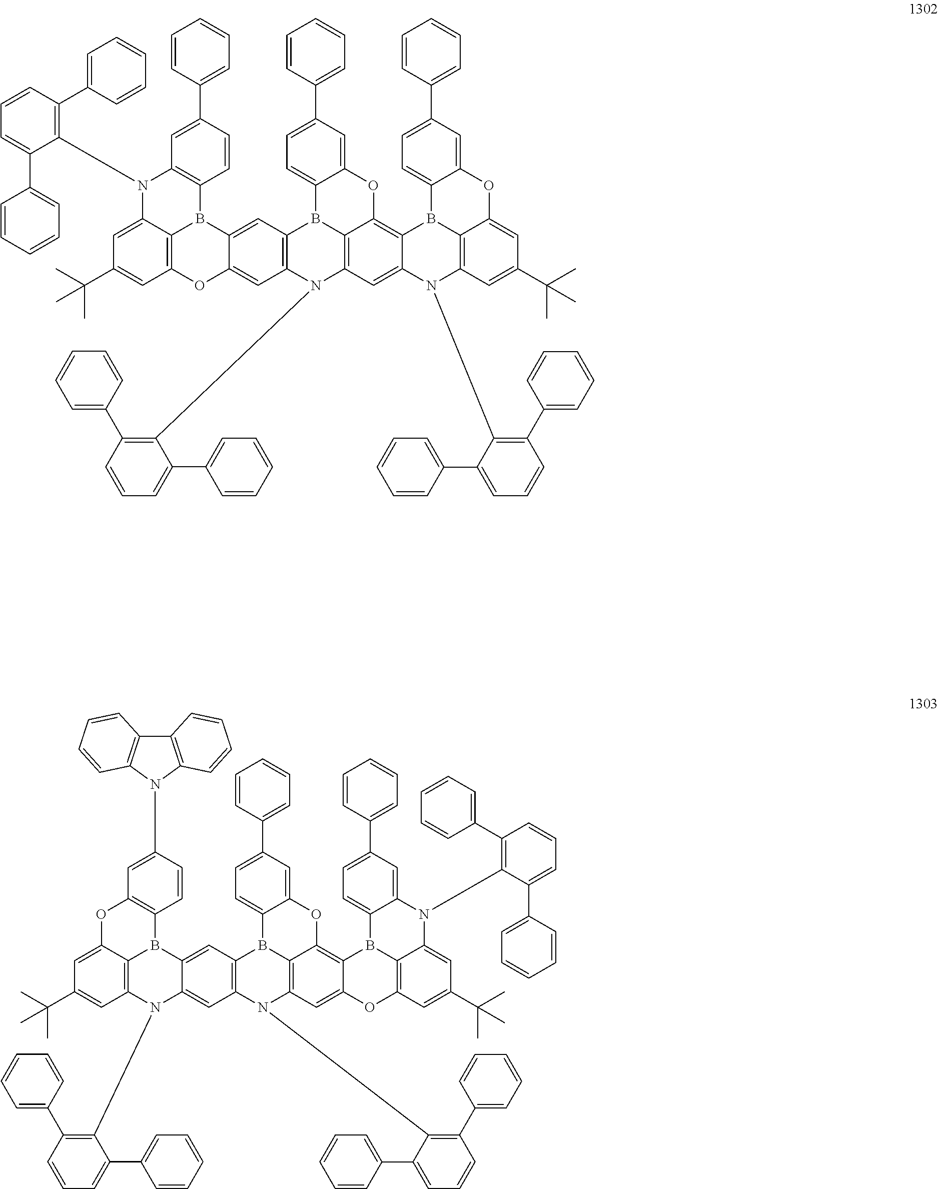 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1] 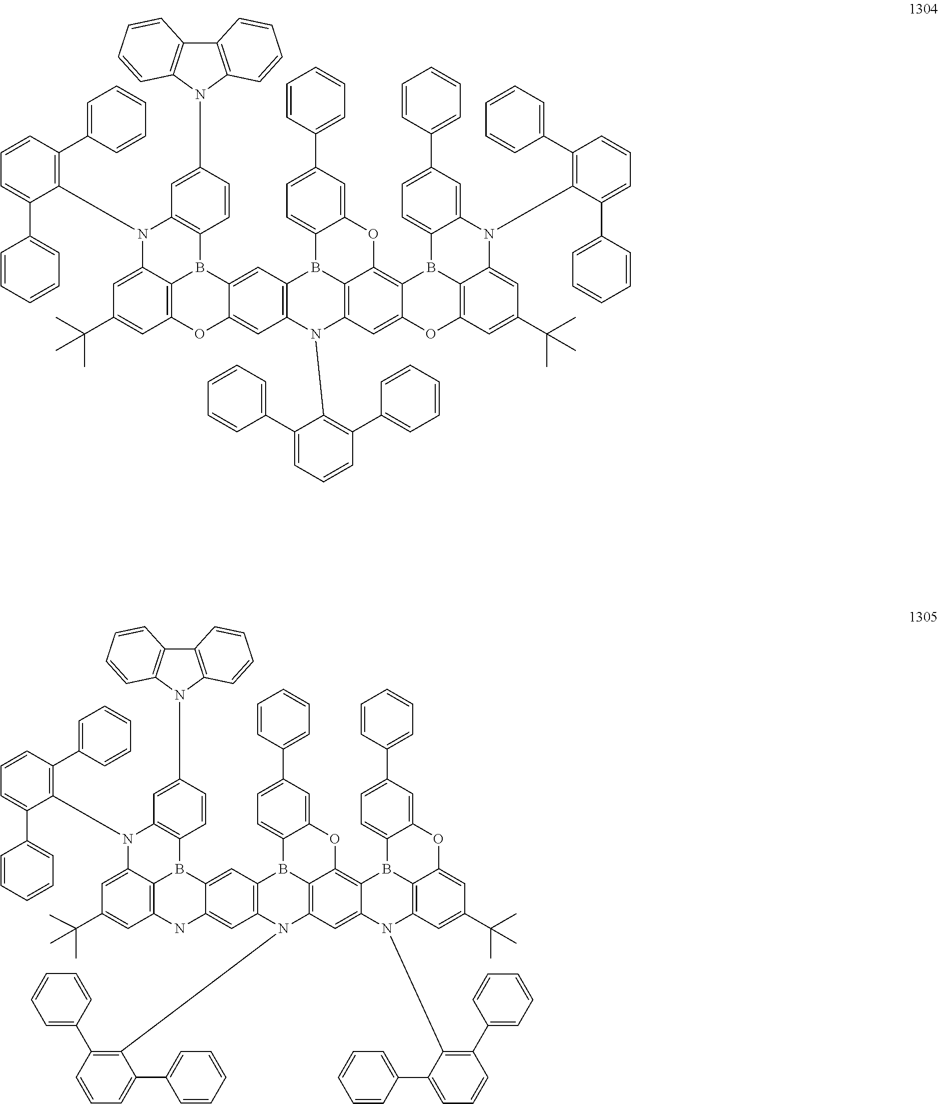 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1N2)N(c1c(-c2ccccc2)cccc1-c1ccccc1)c1cc2c(c4c1B3c1ccc(-c3ccccc3)cc1O4)B1c3ccc(-c4ccccc4)cc3Oc3cc(C(C)(C)C)cc(c31)N2c1c(-c2ccccc2)cccc1-c1ccccc1] 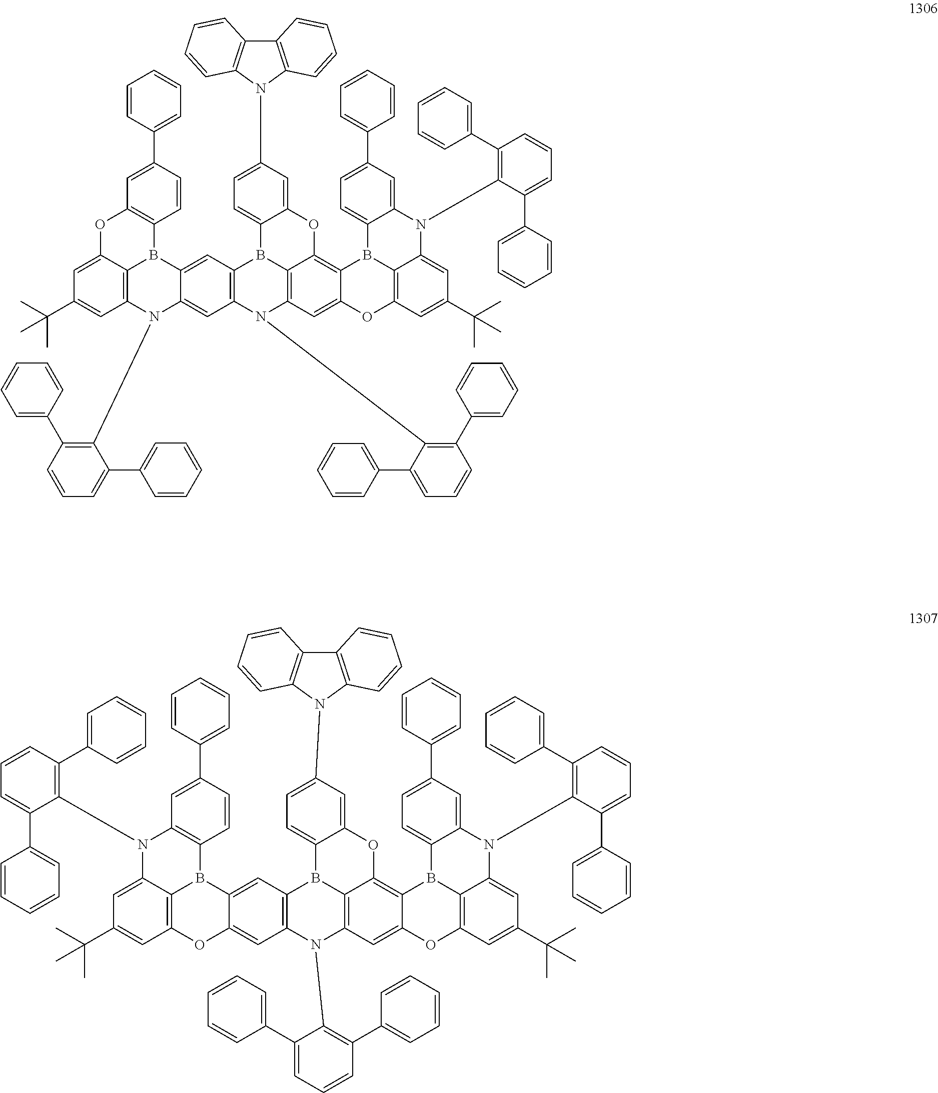 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-n3c5ccccc5c5ccccc53)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-n3c5ccccc5c5ccccc53)cc1O4)B1c3ccc(-c4ccccc4)cc3N(c3c(-c4ccccc4)cccc3-c3ccccc3)c3cc(C(C)(C)C)cc(c31)O2] 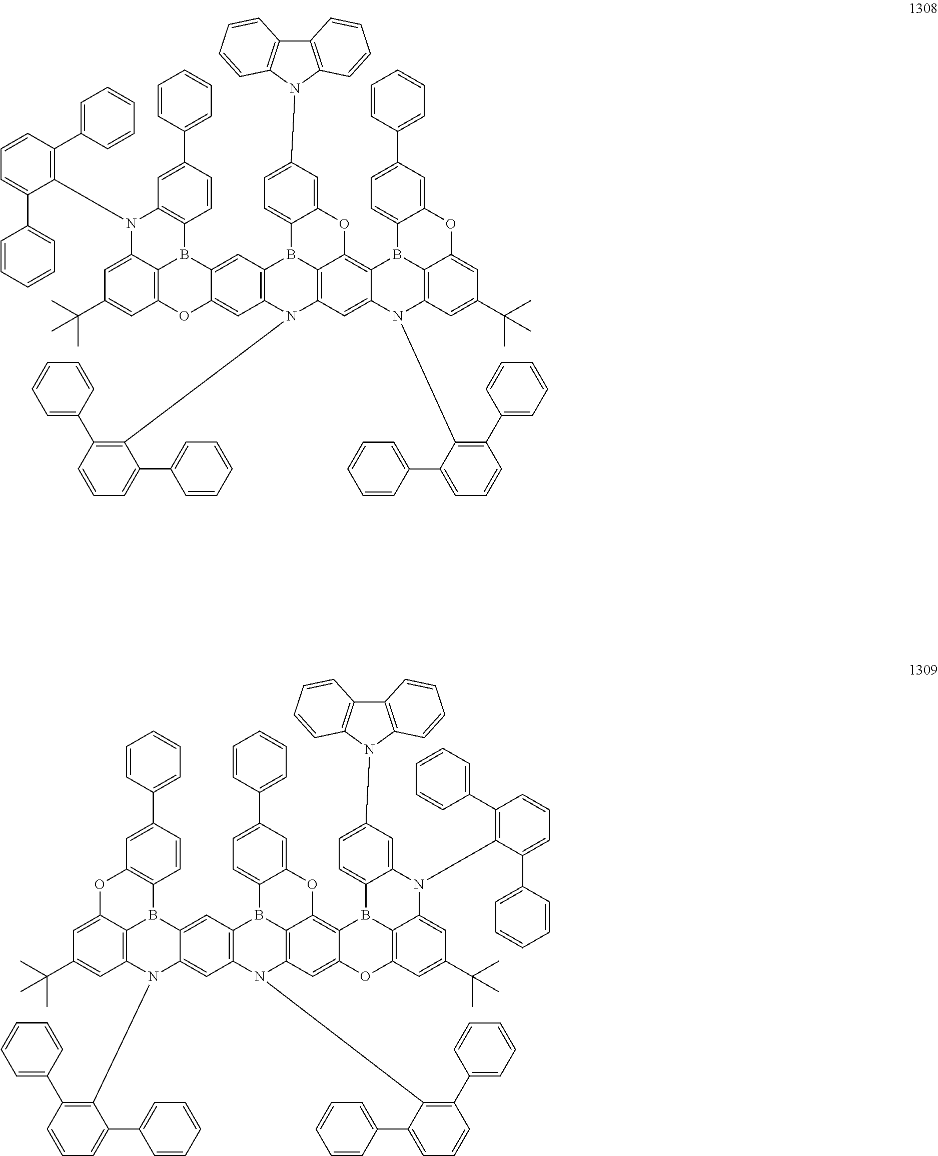 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-n3c5ccccc5c5ccccc53)cc1O4)B1c3ccc(-c4ccccc4)cc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-n3c4ccccc4c4ccccc43)cc1N2c1c(-c2ccccc2)cccc1-c1ccccc1] 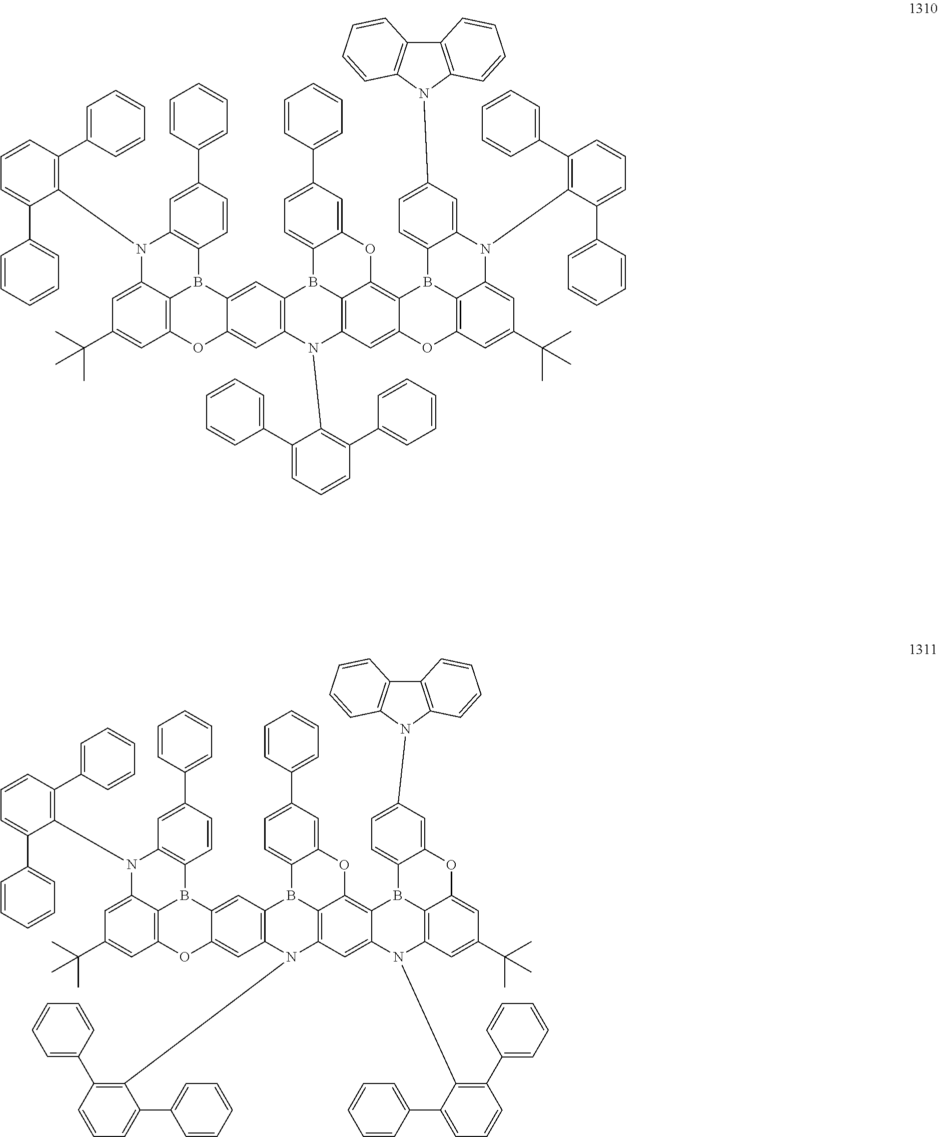 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3N(c3c(-c4ccccc4)cccc3-c3ccccc3)c3cc(C(C)(C)C)cc(c31)O2 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3Oc3cc(C(C)(C)C)cc(c31)N2c1c(-c2ccccc2)cccc1-c1ccccc1] 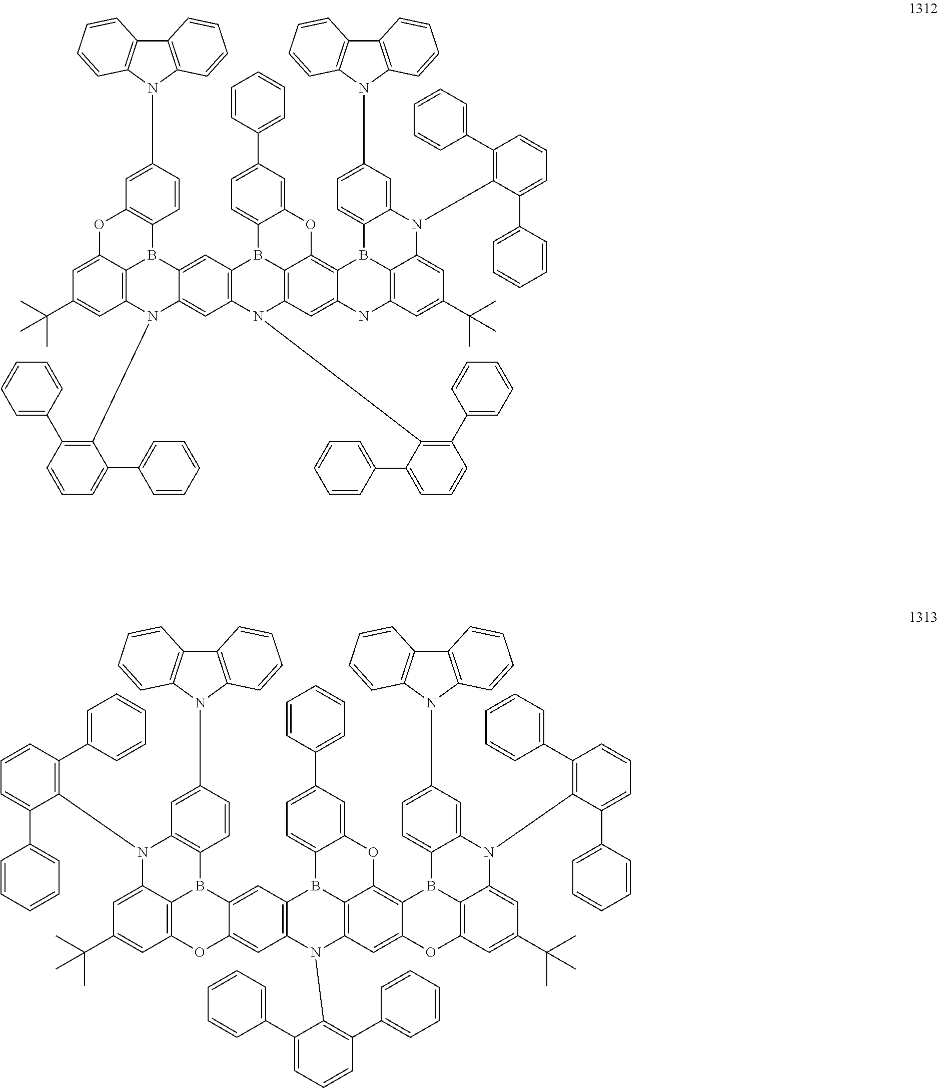 [SMILES: CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1cc(-c5ccccc5)ccc1B4c1cc4c(cc1N3c1c(-c3ccccc3)cccc1-c1ccccc1)N(c1c(-c3ccccc3)cccc1-c1ccccc1)c1cc(C(C)(C)C)cc3c1B4c1ccc(-n4c5ccccc5c5ccccc54)cc1O3)N2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-n4c5ccccc5c5ccccc54)cc3N(c3c(-c4ccccc4)cccc3-c3ccccc3)c3cc(C(C)(C)C)cc(c31)O2] 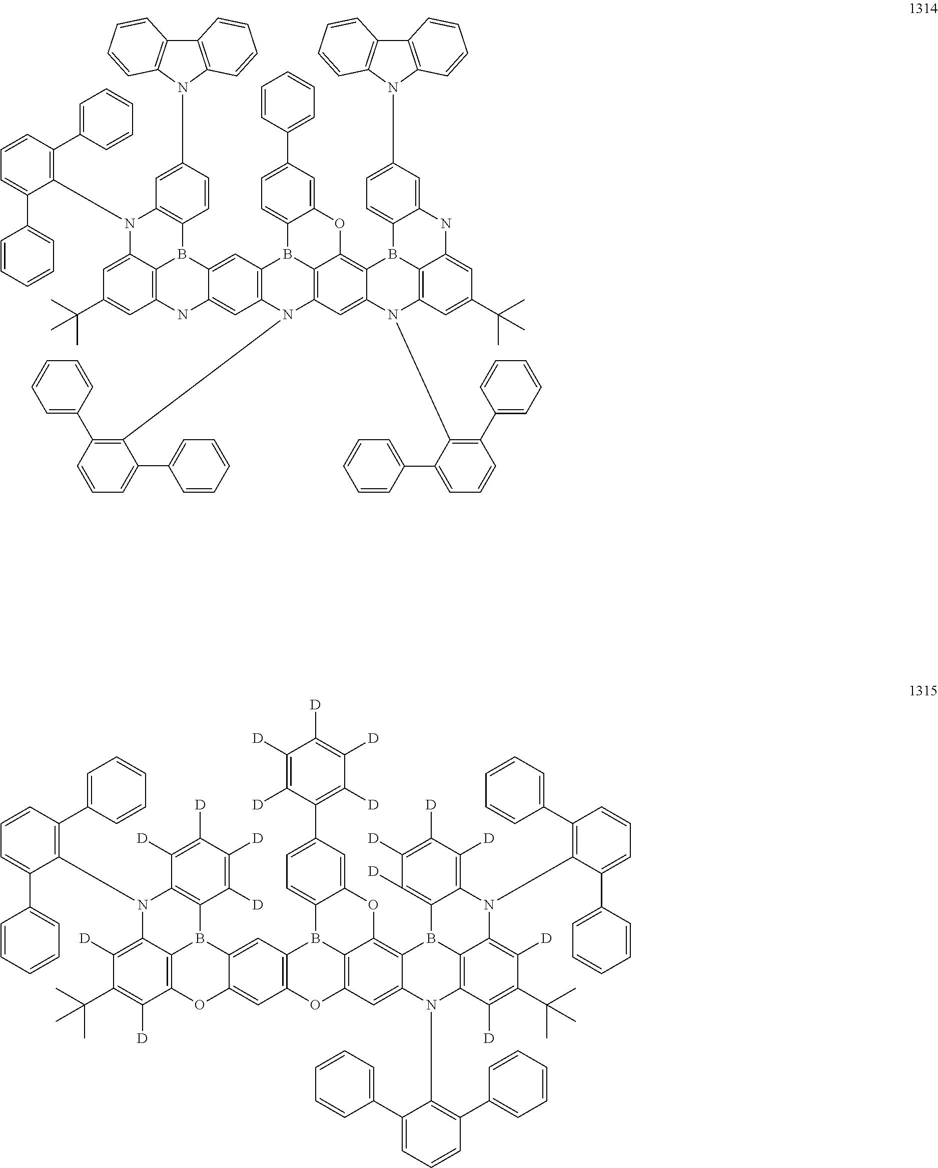 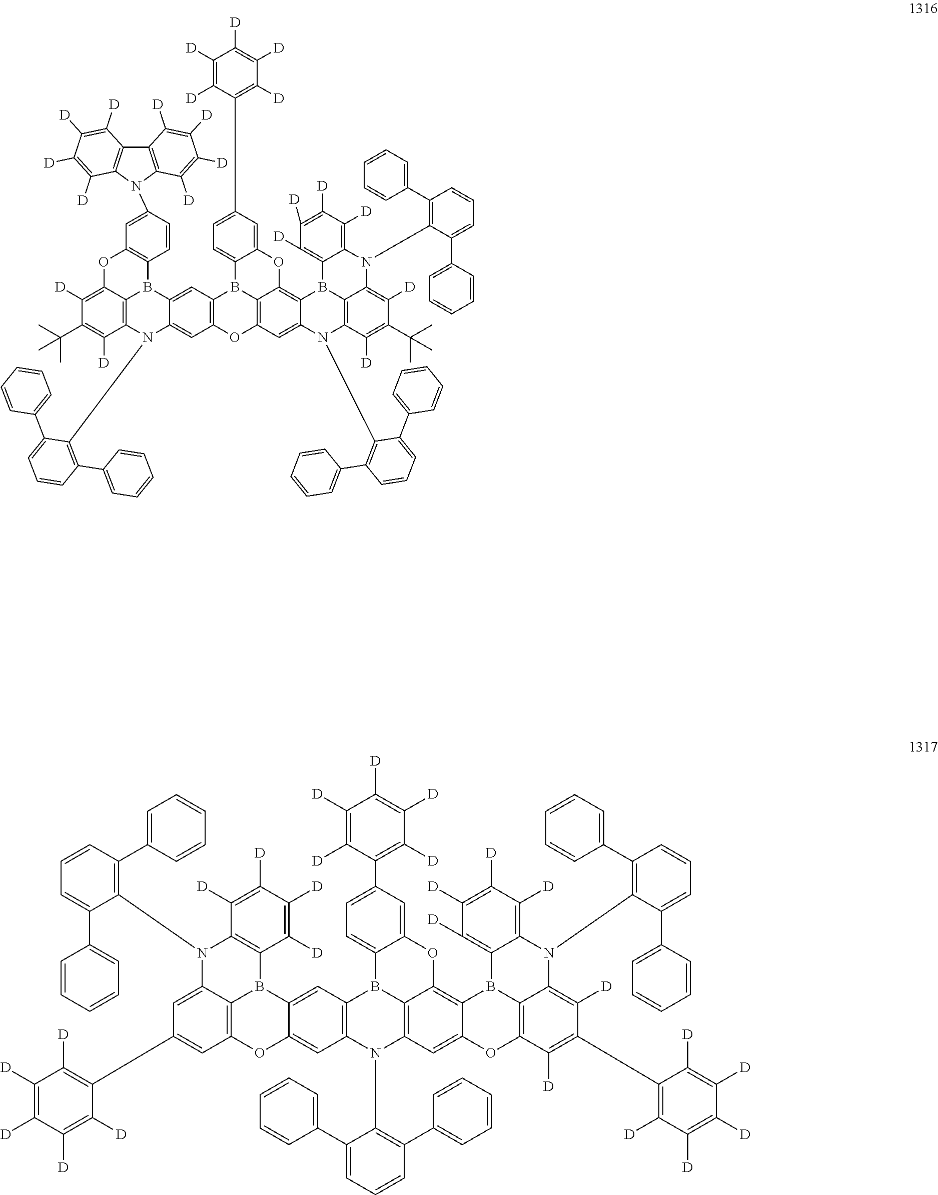 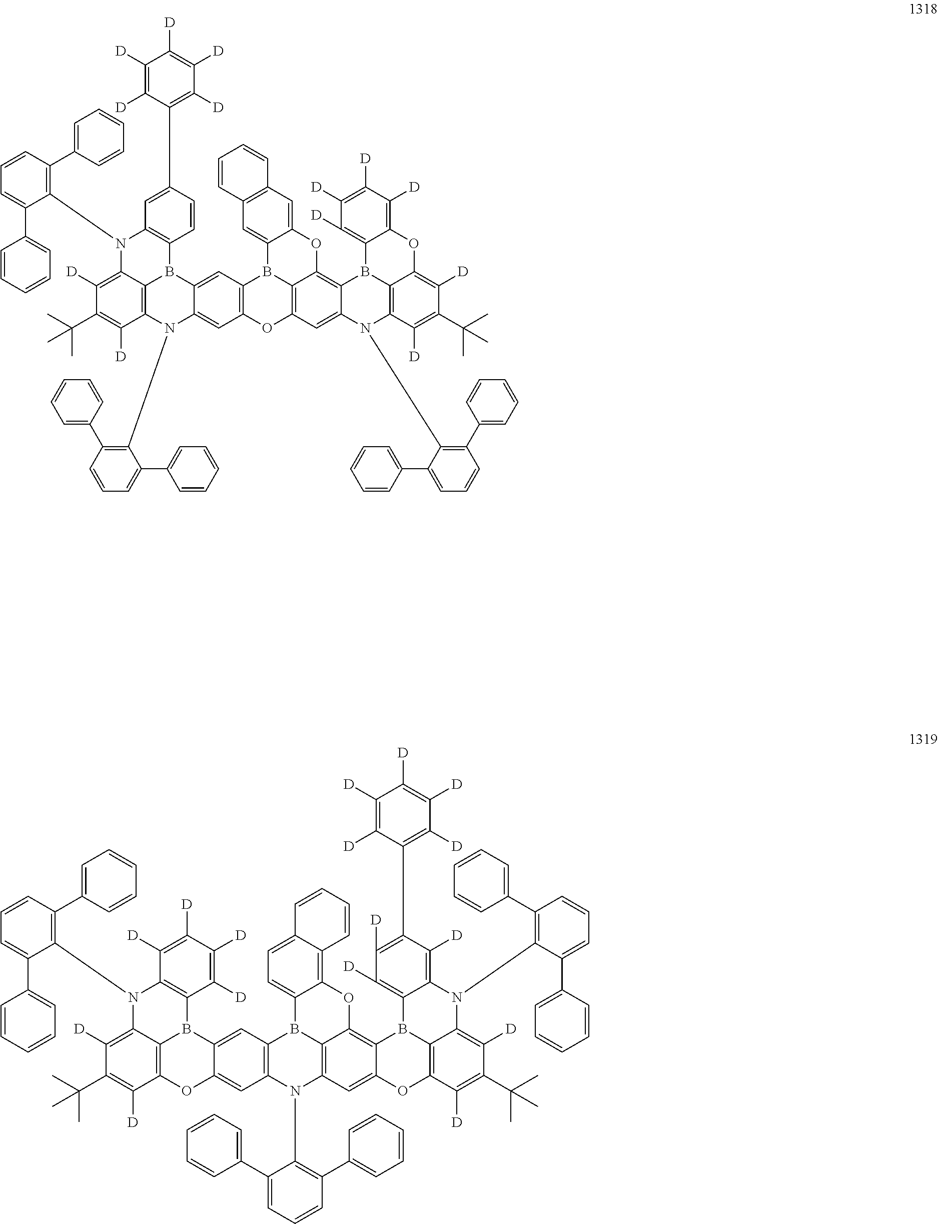
in Compound Group 1, D being deuterium.

11. A fused polycyclic compound represented by Formula 1: 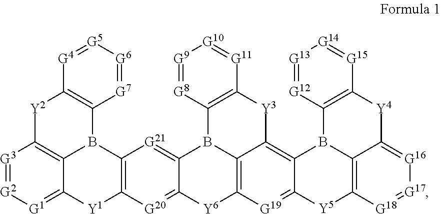
wherein in Formula 1,
Y¹ to Y⁶ are each independently O, S, or NR^{y}, at least one selected from among G¹ to G²¹ is CR^{x1}, and the others are each independently N or CR^{x2},
R^{x1} is deuterium, halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
R^{x2} and R^{y} are each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
when G² is CR^{x1} or CR^{x2}, then R^{x1} and R^{x2} are not substituted or unsubstituted amine groups,
when G¹⁷ is CR^{x1} or CR^{x2}, then R^{x1} and R^{x2} are not substituted or unsubstituted amine groups, and
the fused polycyclic compound comprises a chemical structure in which one or more hydrogens of the fused polycyclic compound are optionally substituted with deuterium.

12. The fused polycyclic compound of claim 11, wherein the fused polycyclic compound represented by Formula 1 is represented by any one selected from among Formulas 1-A1 to 1-A8: 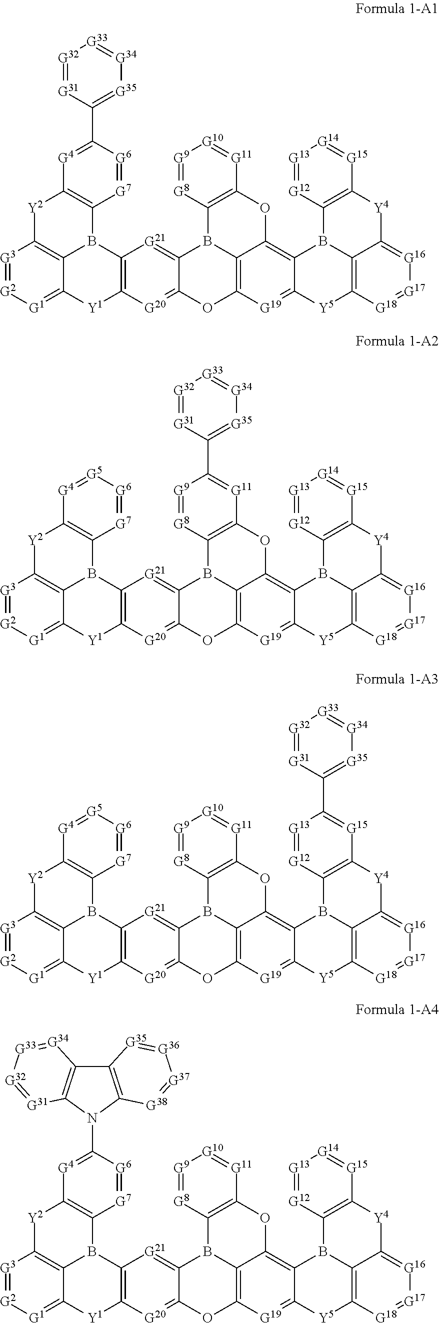 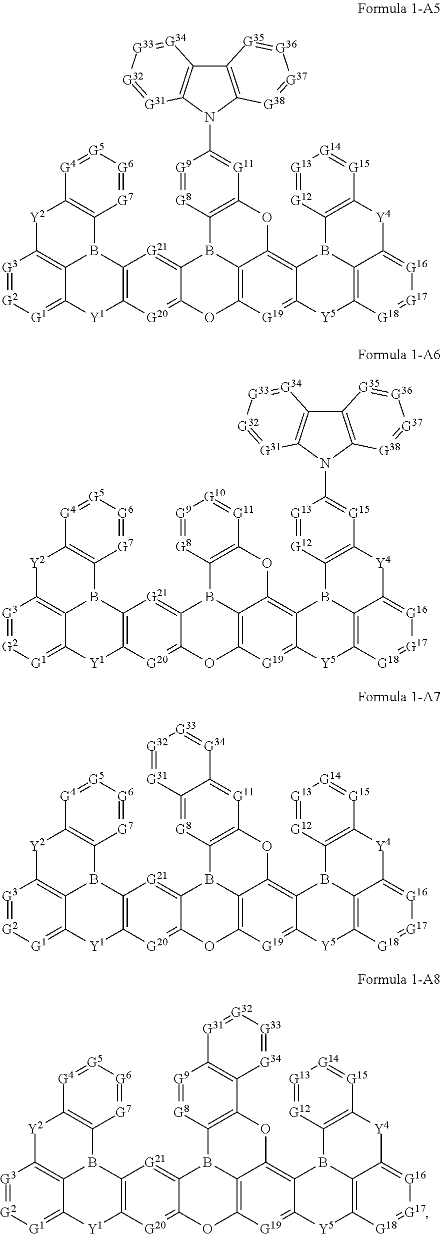
in Formulas 1-A1 to 1-A8,
G³¹ to G³⁸ being each independently N or CR^{X3},
R^{X3} being hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
Y¹, Y², Y⁴, and Y⁵, and G¹ to G²¹ being each the same as defined in Formula 1.

13. The fused polycyclic compound of claim 11, wherein the fused polycyclic compound represented by Formula 1 is represented by any one selected from among Formulas 1-B1 to 1-B4: 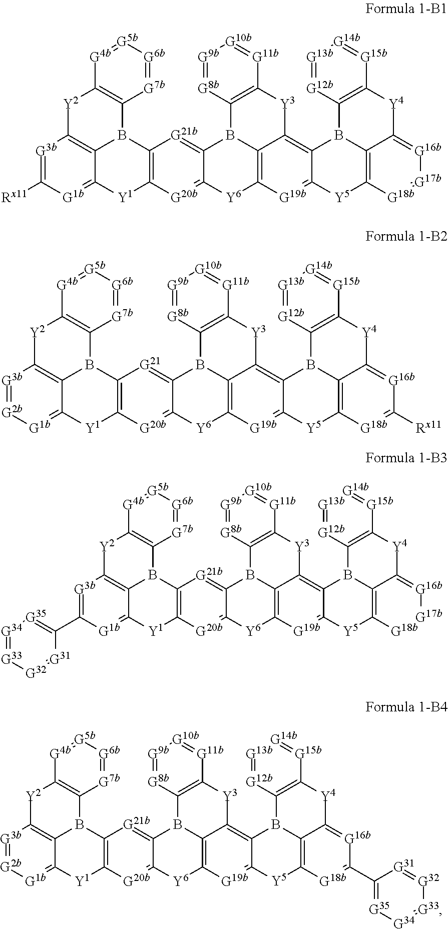
in Formulas 1-B1 to 1-B4,
G^{1b} to G^{21b} and G³¹ to G³⁵ being each independently N or CR^{x2},
R^{x11} being a substituted or unsubstituted alkyl group having 1 to 20 carbon atoms, and
Y¹ to Y⁶ and R^{x2} being each the same as defined in Formula 1.

14. The fused polycyclic compound of claim 11, wherein the fused polycyclic compound represented by Formula 1 is represented by Formula 2: 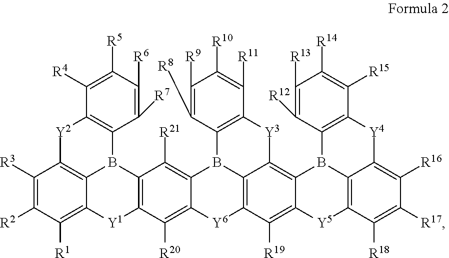
in Formula 2,
R¹ to R²¹ being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
at least one selected from among R¹ to R²¹ being not hydrogen,
R² and R¹⁷ being not each a substituted or unsubstituted amine group, and
Y¹ to Y⁶ being each the same as defined in Formula 1.

15. The fused polycyclic compound of claim 14, wherein the fused polycyclic compound represented by Formula 2 is represented by any one selected from among Formulas 2-A1 to 2-A5 and Formulas 2-B1 to 2-B10: 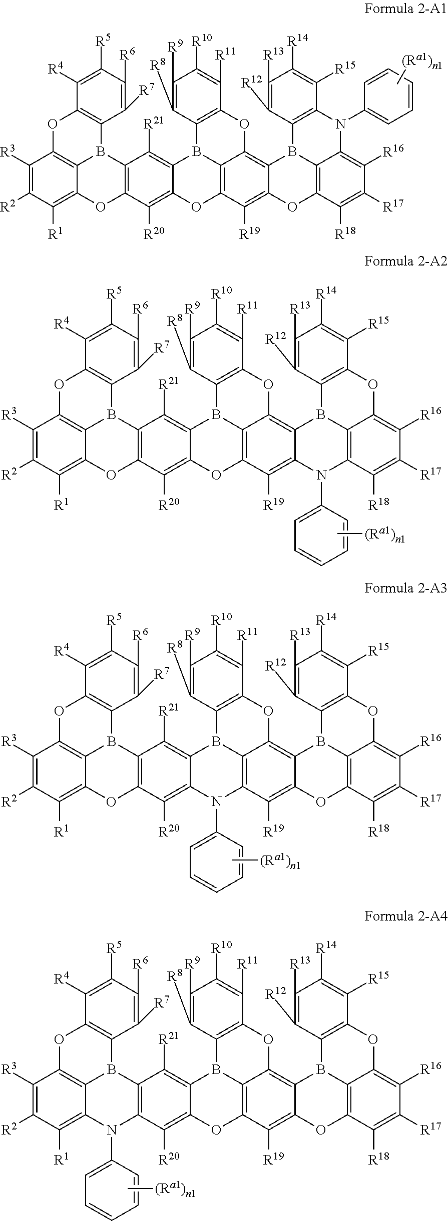 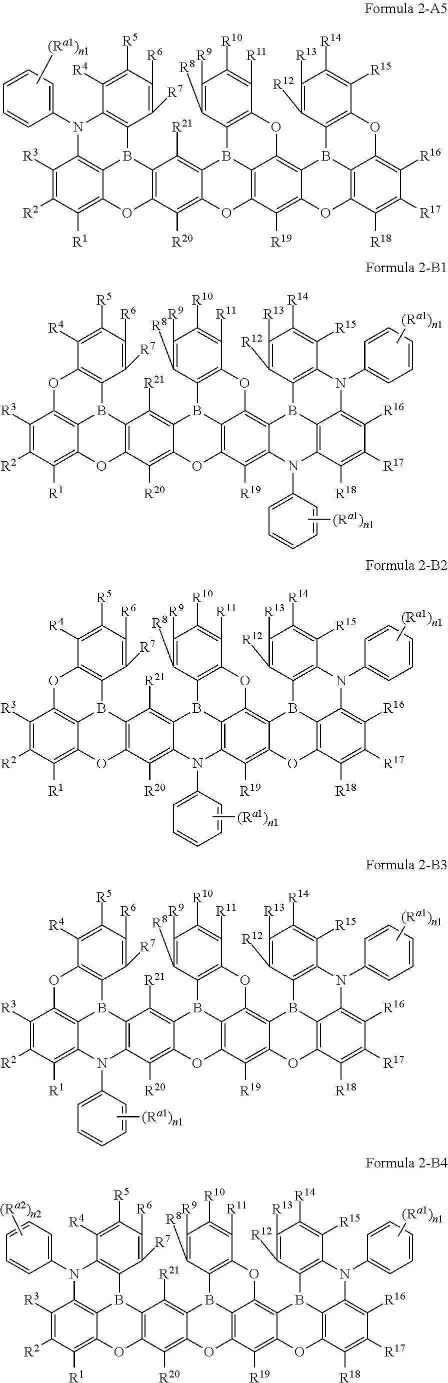 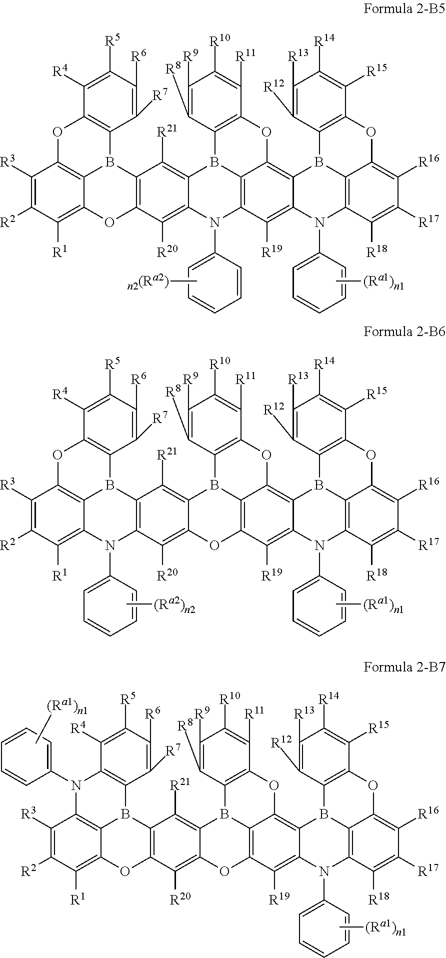 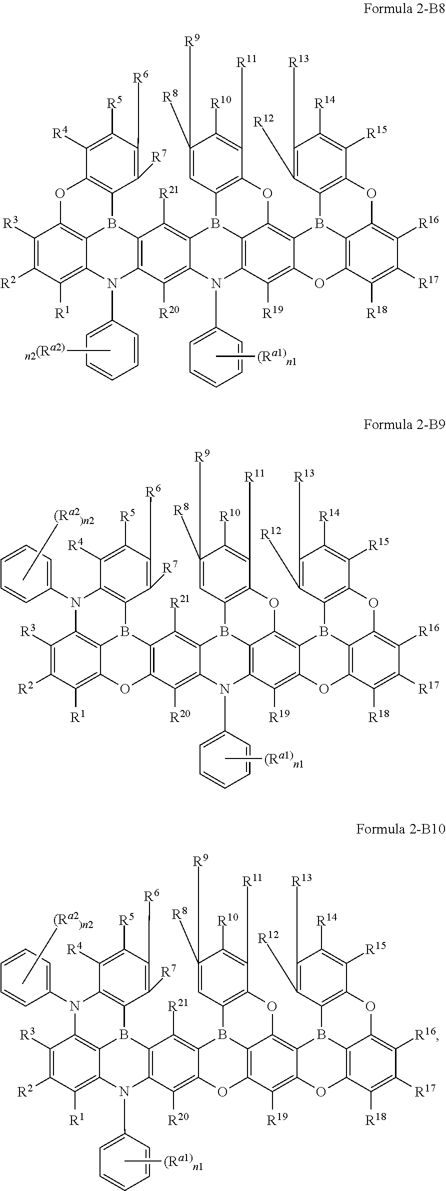
in Formulas 2-A1 to 2-A5 and Formulas 2-B1 to 2-B10,
n1 and n2 being each independently an integer of 0 to 5,
R^{a1} and R^{a2} being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
R¹ to R²¹ being each the same as defined in Formula 2.

16. The fused polycyclic compound of claim 14, wherein the fused polycyclic compound represented by Formula 2 is represented by any one selected from among Formulas 2-C1 to 2-C10 and Formulas 2-D1 to 2-D5: 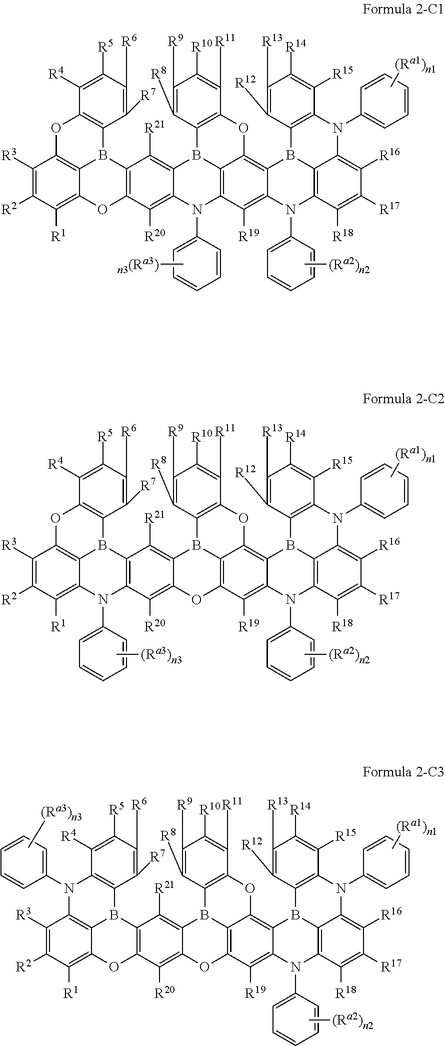 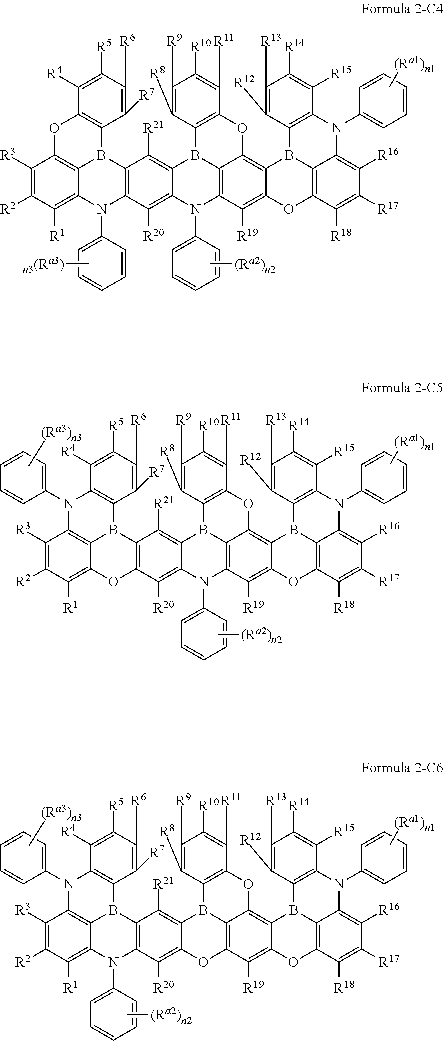 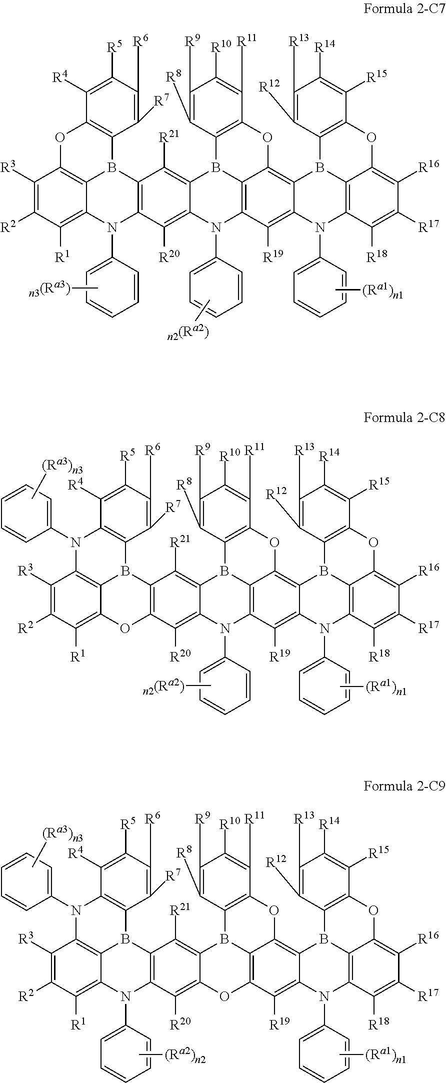 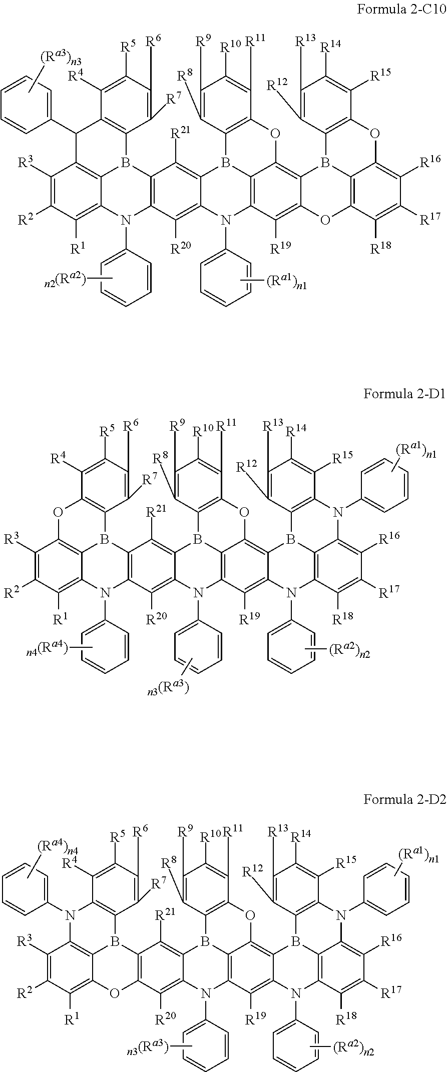 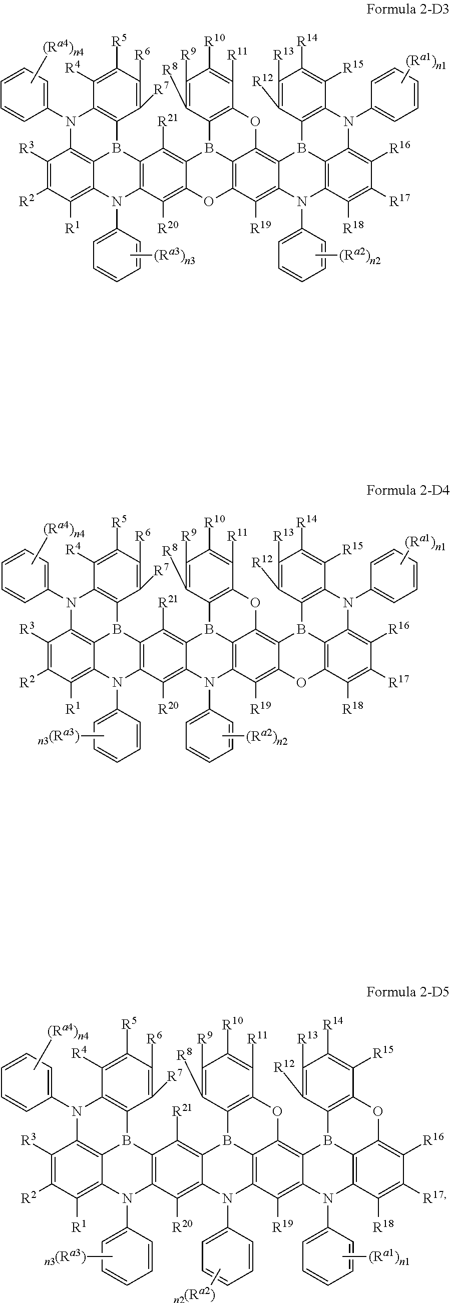
in Formulas 2-C1 to 2-C10 and Formulas 2-D1 to 2-D5,
n1 to n4 being each independently an integer of 0 to 5,
R^{a1} to R^{a4} being each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring, and
R¹ to R²¹ being each the same as defined in Formula 2.

17. The fused polycyclic compound of claim 14, wherein in Formula 2, the at least one selected from among R¹ to R²¹ is a substituted or unsubstituted t-butyl group, a substituted or unsubstituted phenyl group, or a substituted or unsubstituted carbazole group.

18. The fused polycyclic compound of claim 11, wherein the fused polycyclic compound represented by Formula 1 is any one selected from among compounds from Compound Group 1: 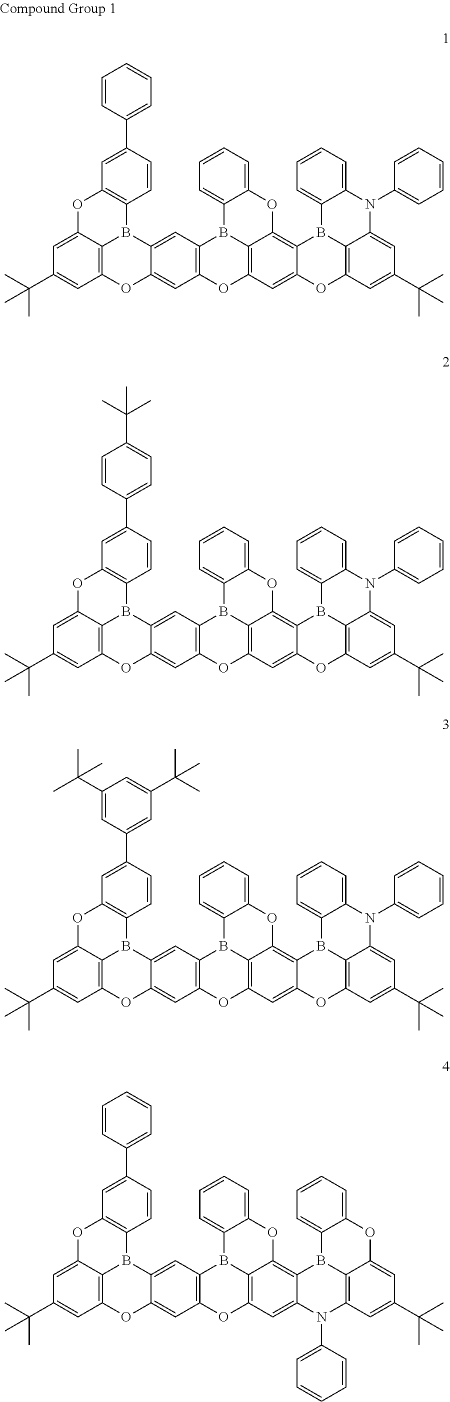 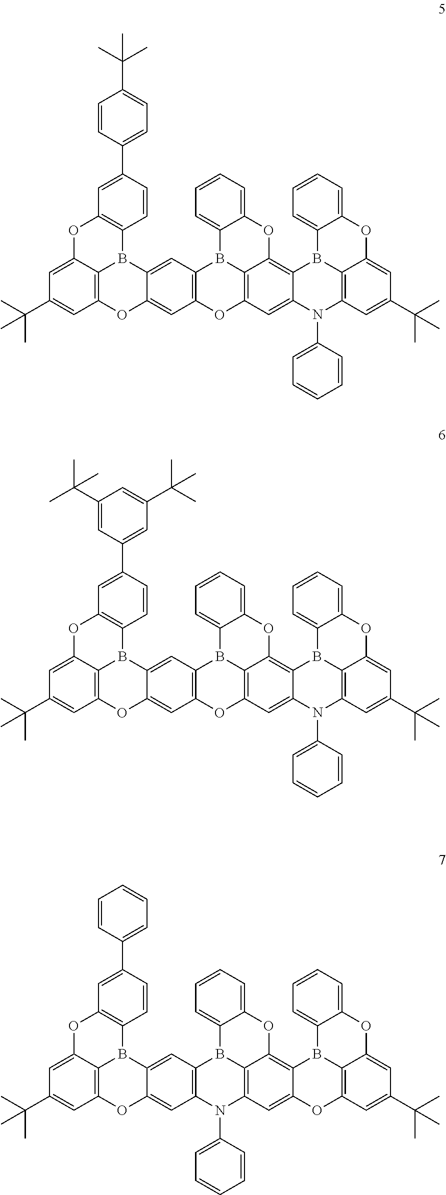 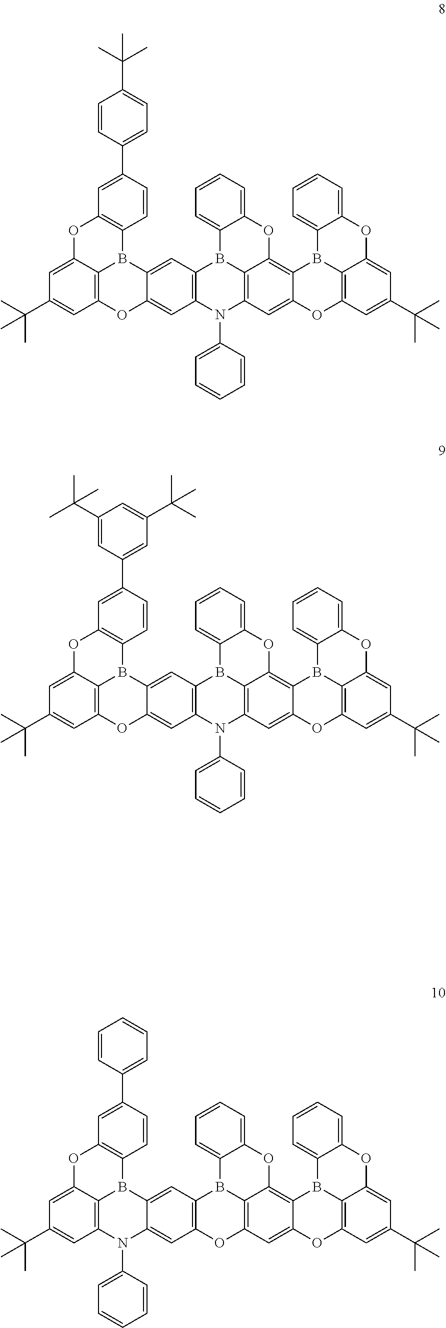 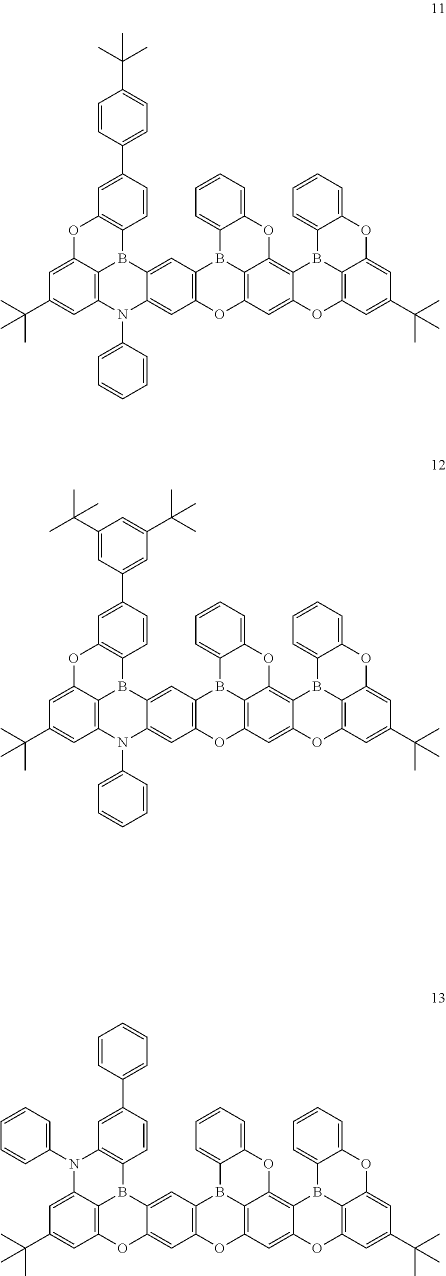 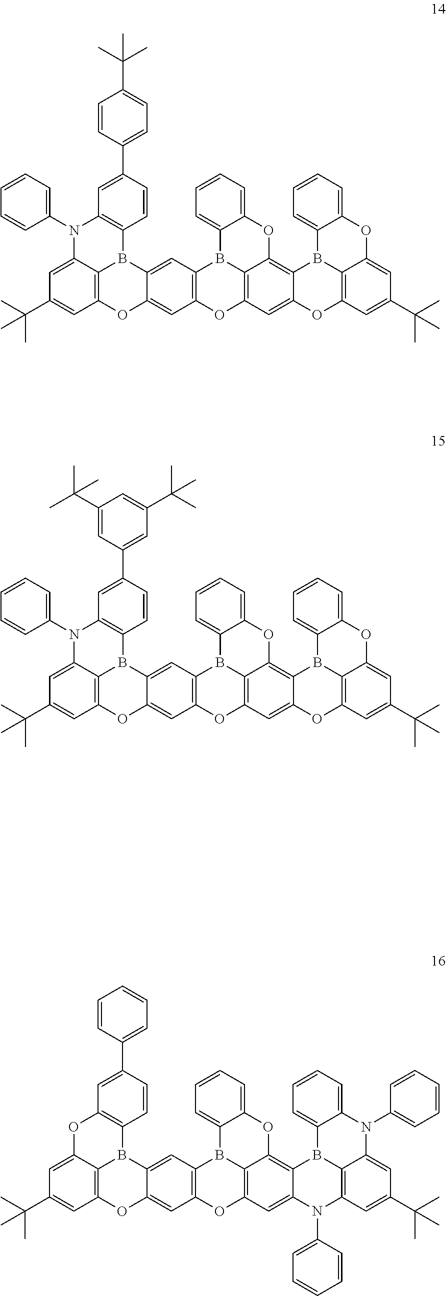 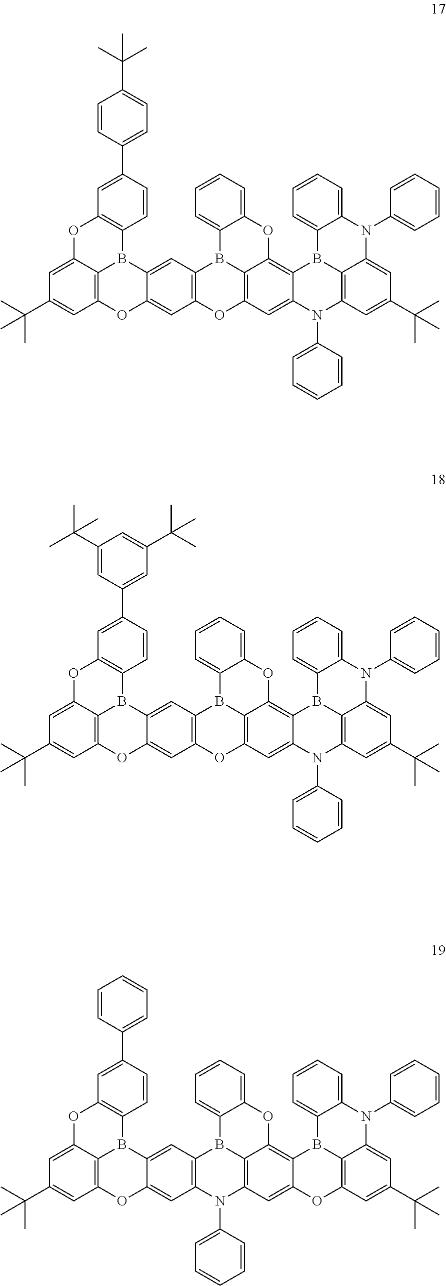 [SMILES: CC(C)(C)c1ccc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)Oc1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1] 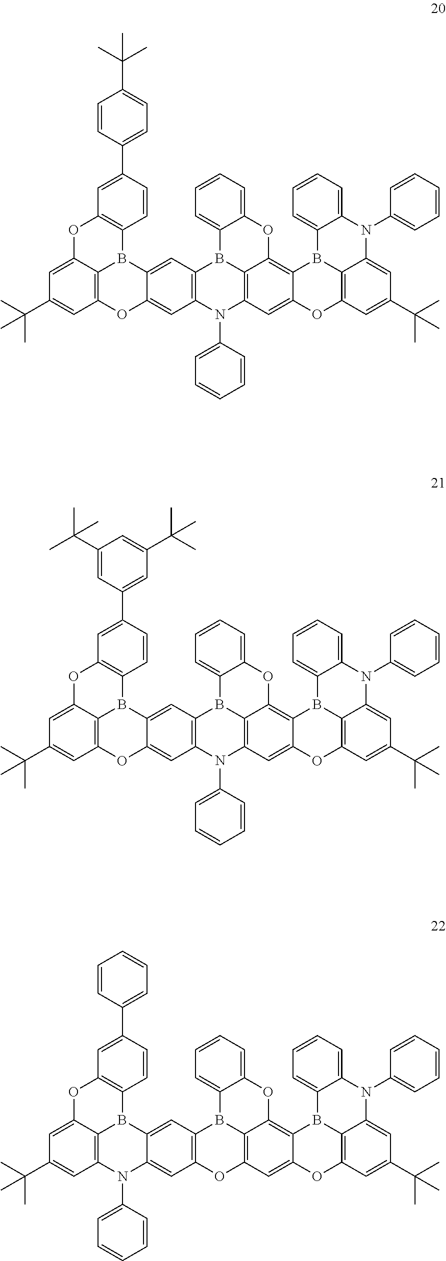 [SMILES: CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1 ; CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)O1)O4] 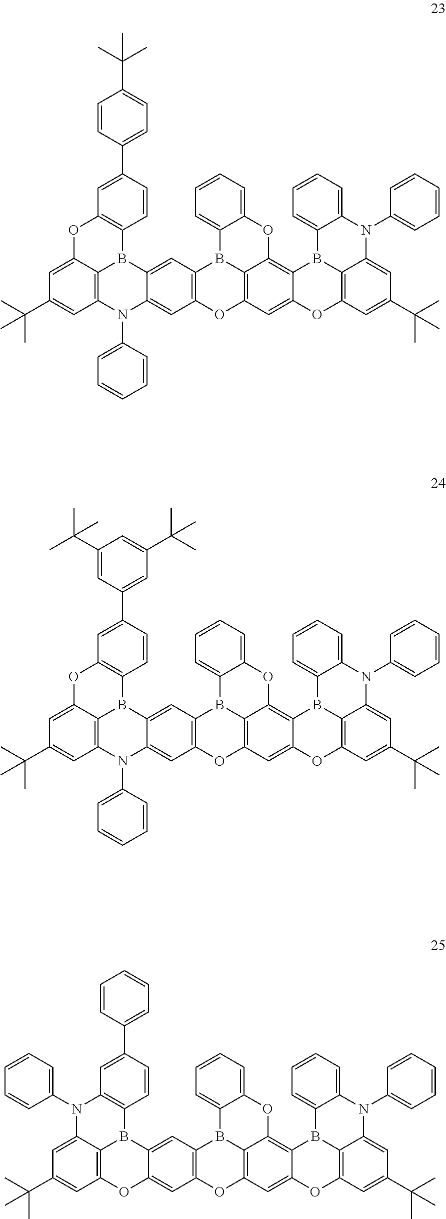 [SMILES: CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1 ; CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)O2] 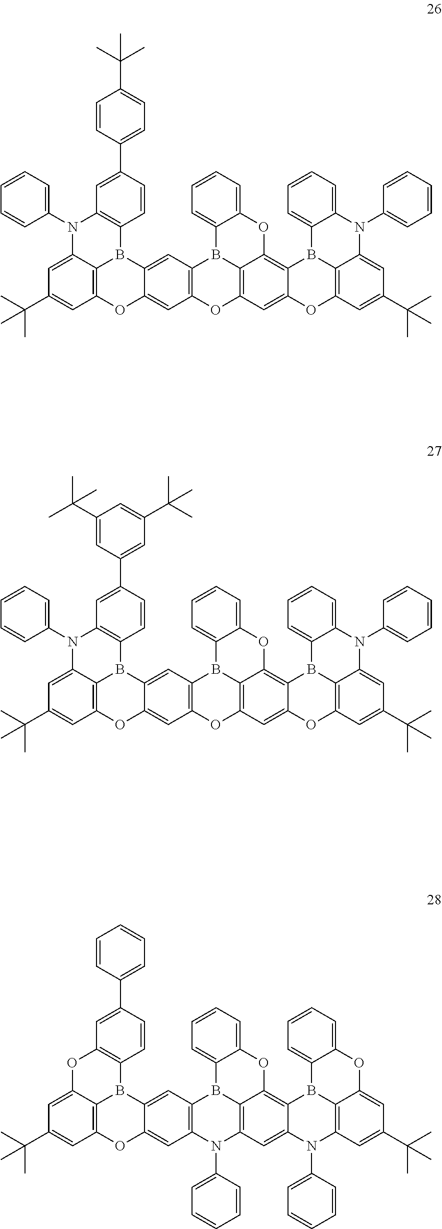 [SMILES: CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)O4)cc(C(C)(C)C)c1 ; CC(C)(C)c1cc2c3c(c1)Oc1cc4c(cc1B3c1ccc(-c3ccccc3)cc1O2)B1c2ccccc2Oc2c1c(cc1c2B2c3ccccc3Oc3cc(C(C)(C)C)cc(c32)N1c1ccccc1)N4c1ccccc1] 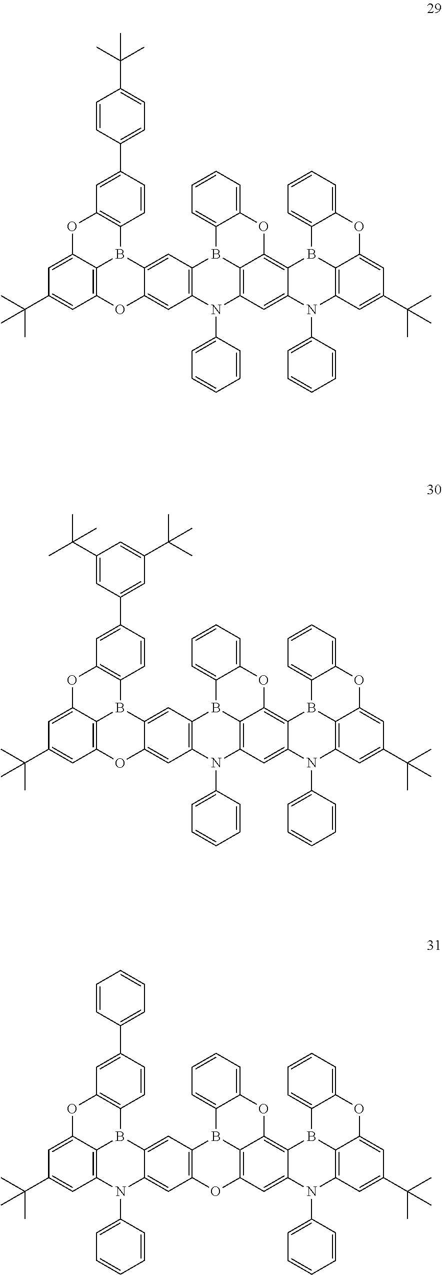 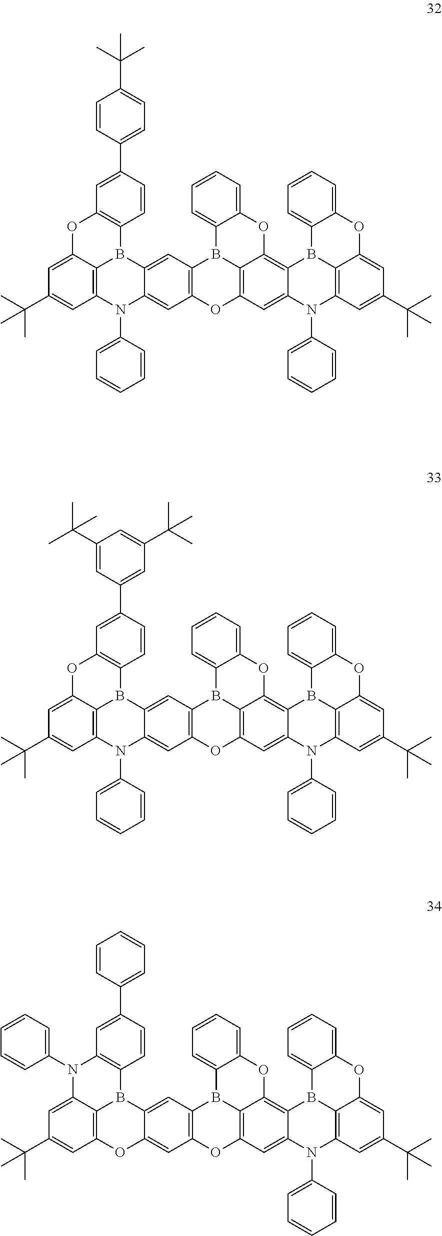 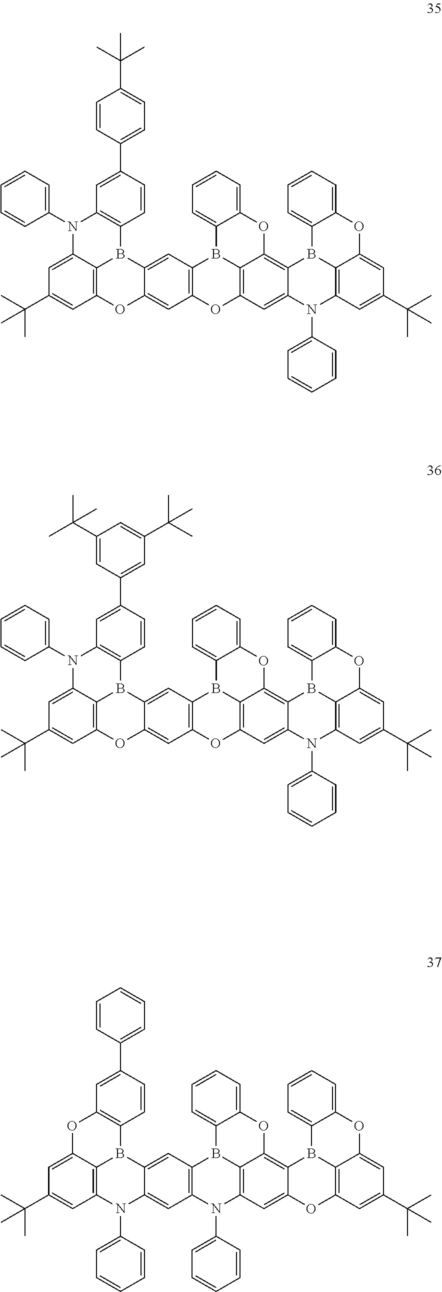 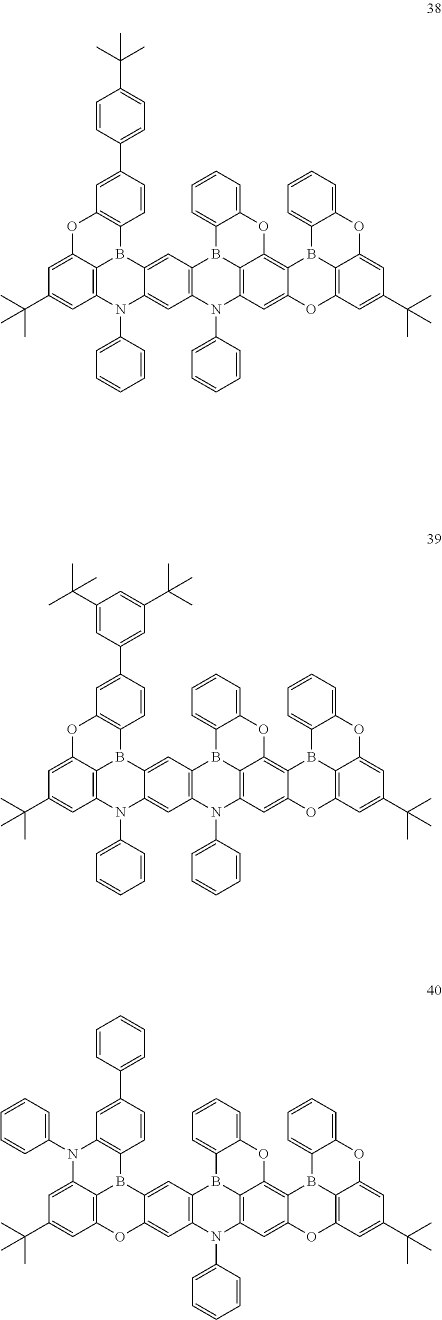 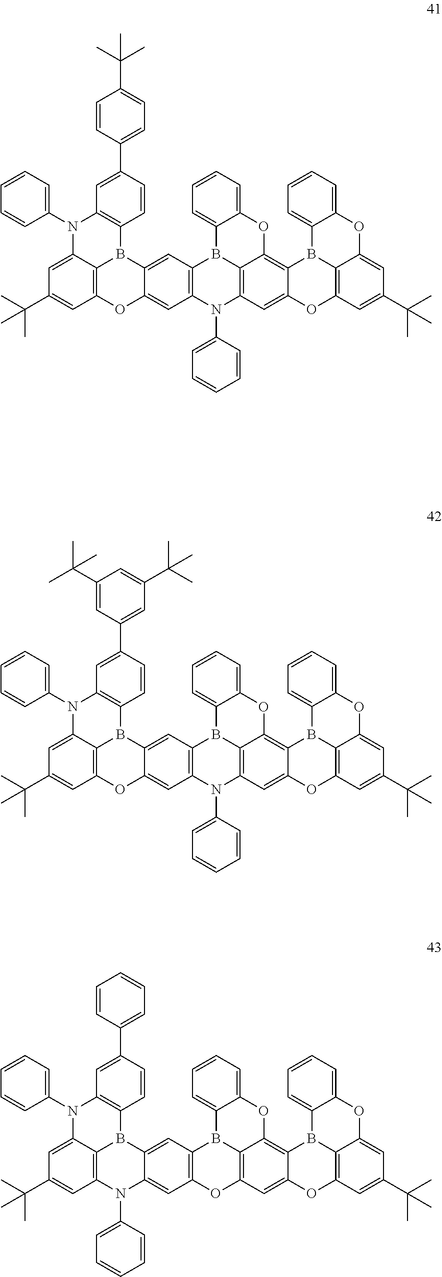 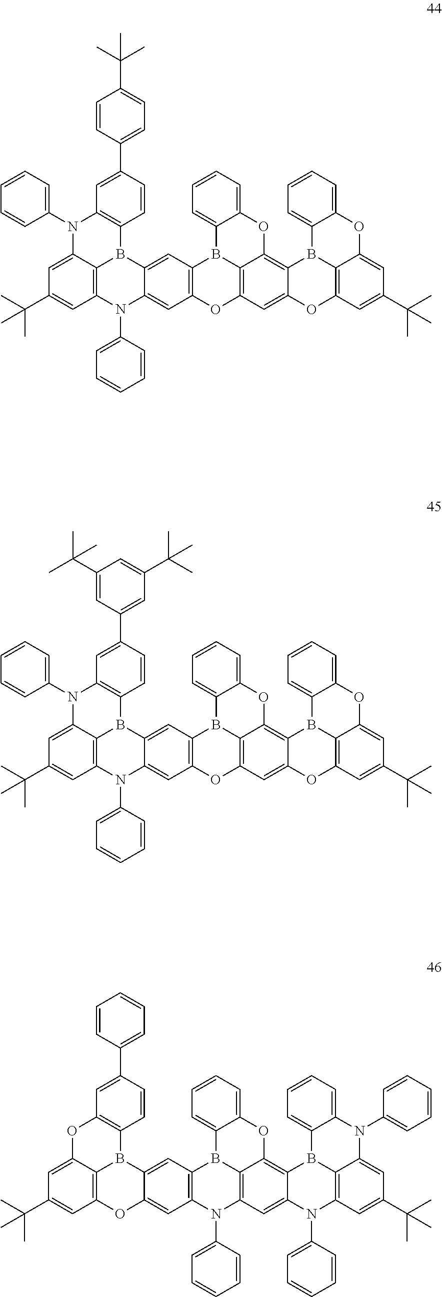 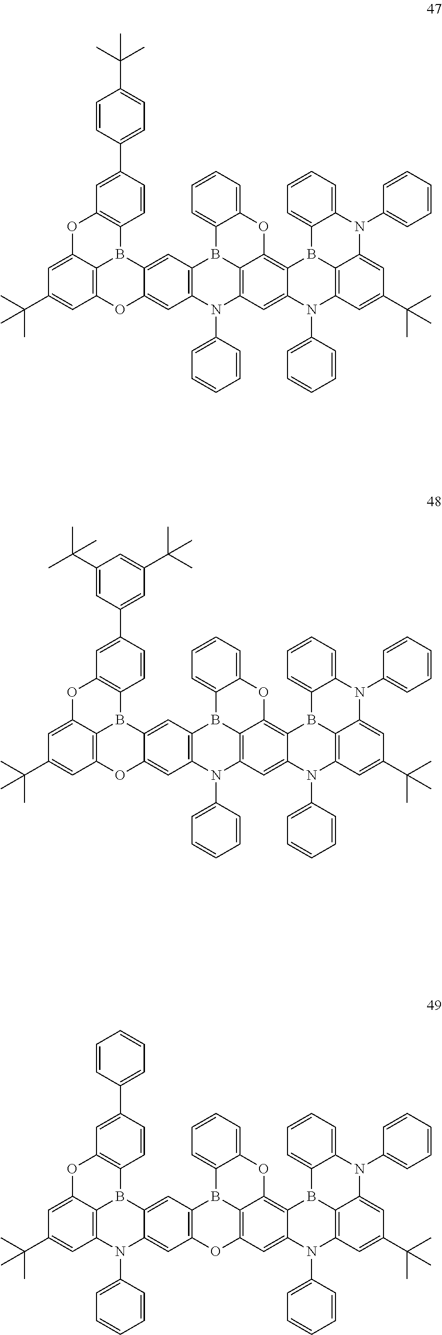 [SMILES: CC(C)(C)c1ccc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)O4] 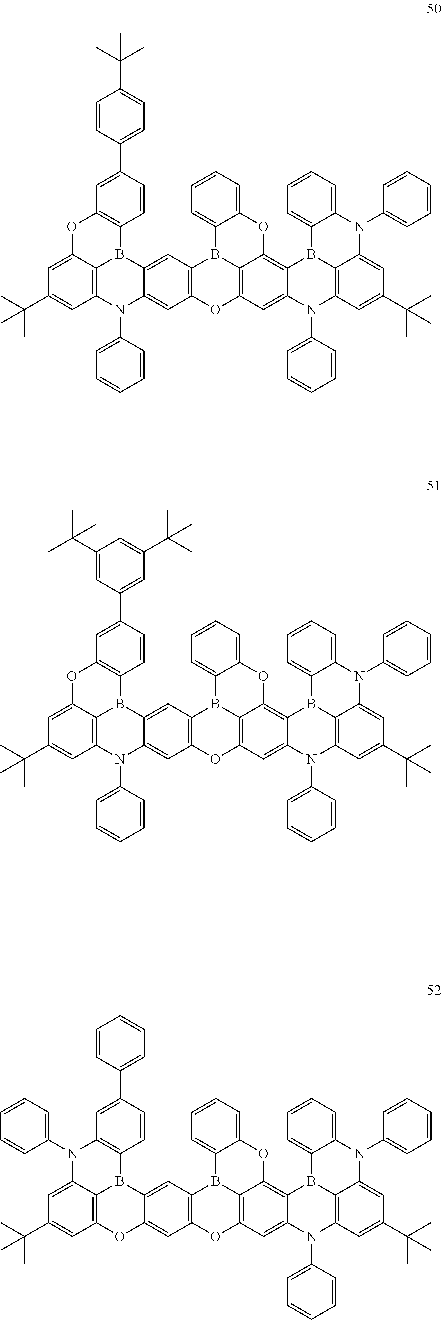 [SMILES: CC(C)(C)c1ccc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1cc(-c4ccccc4)ccc1B3c1cc3c(cc1O2)Oc1cc2c(c4c1B3c1ccccc1O4)B1c3ccccc3N(c3ccccc3)c3cc(C(C)(C)C)cc(c31)N2c1ccccc1] 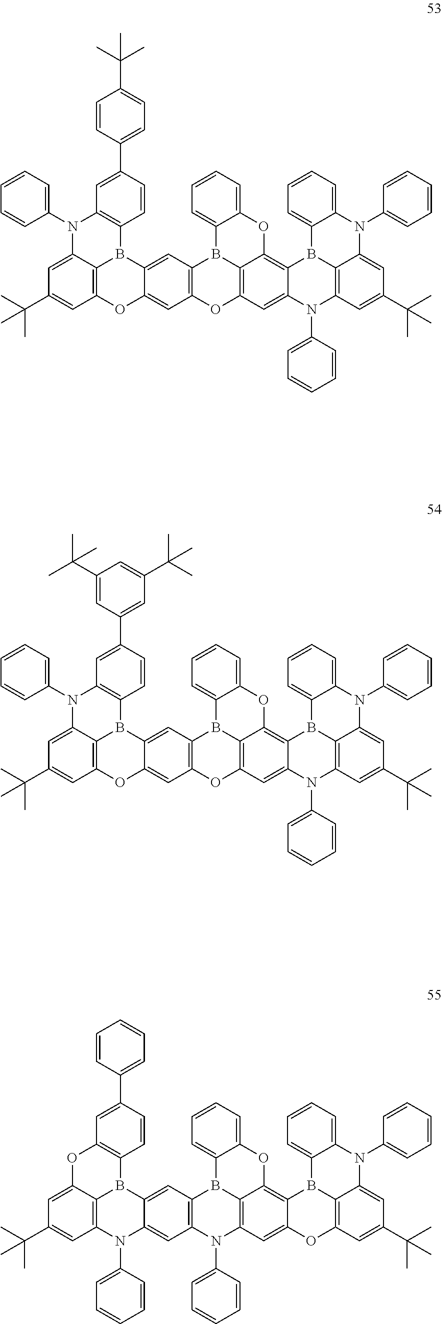 [SMILES: CC(C)(C)c1ccc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2O4)Oc2cc4c(c5c2B3c2ccccc2O5)B2c3ccccc3N(c3ccccc3)c3cc(C(C)(C)C)cc(c32)N4c2ccccc2)cc(C(C)(C)C)c1 ; CC(C)(C)c1cc2c3c(c1)N(c1ccccc1)c1cc4c(cc1B3c1ccc(-c3ccccc3)cc1O2)B1c2ccccc2Oc2c3c(cc(c21)N4c1ccccc1)Oc1cc(C(C)(C)C)cc2c1B3c1ccccc1N2c1ccccc1] 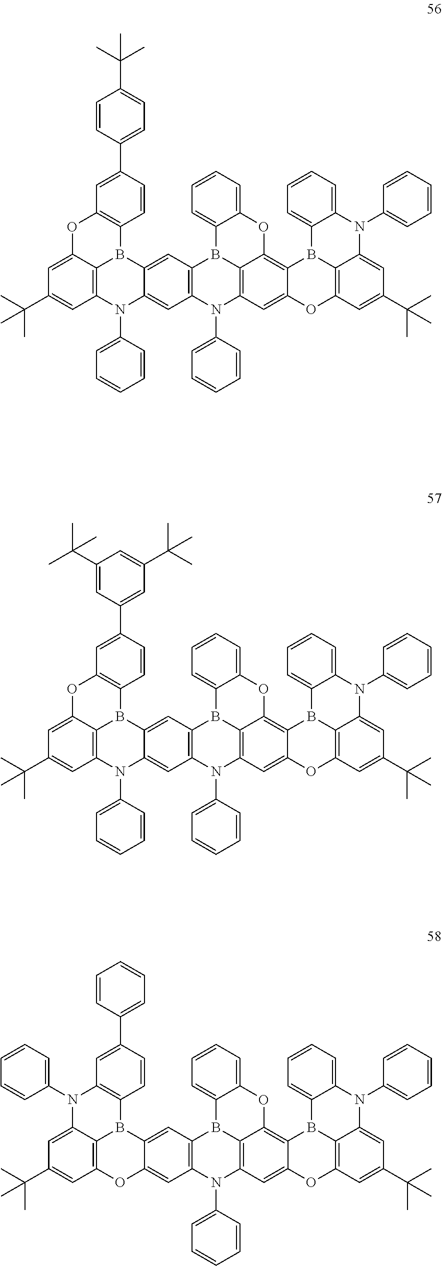 [SMILES: CC(C)(C)c1ccc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1 ; CC(C)(C)c1cc2c3c(c1)N(c1ccccc1)c1cc(-c4ccccc4)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)O2] 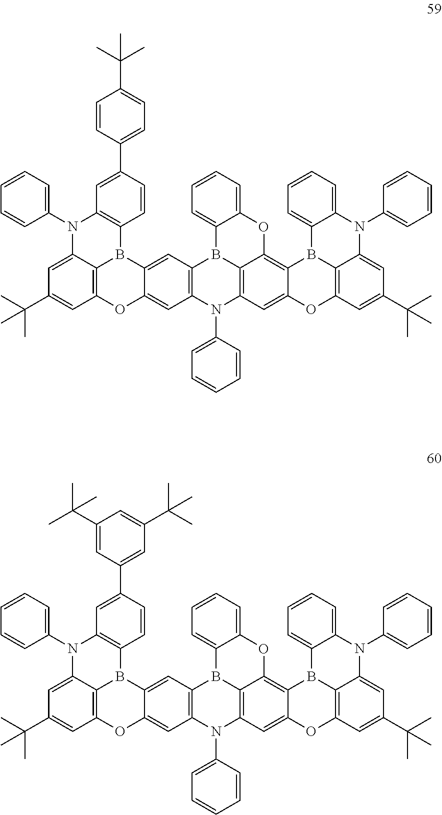 [SMILES: CC(C)(C)c1ccc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1] 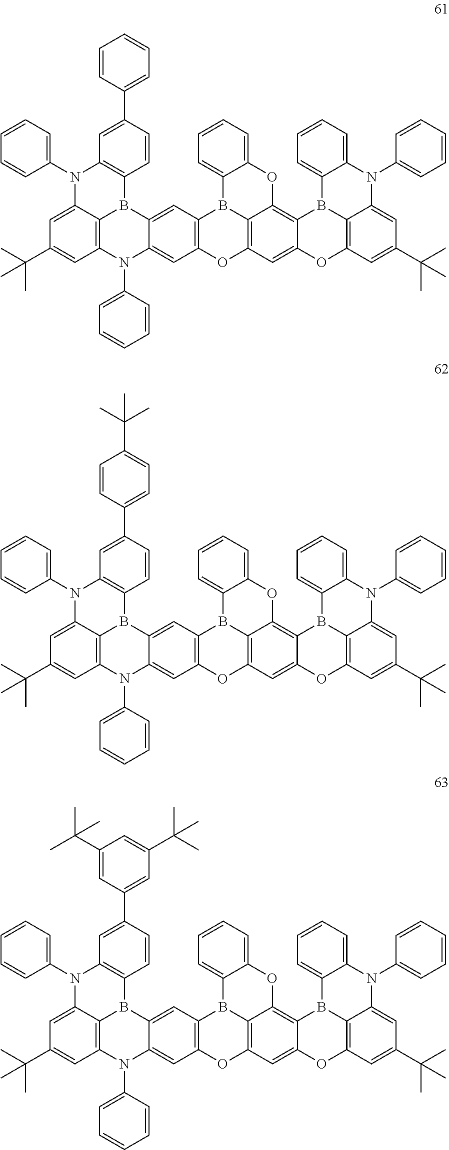 [SMILES: CC(C)(C)c1cc2c3c(c1)N(c1ccccc1)c1ccccc1B3c1c(cc3c4c1Oc1ccccc1B4c1cc4c(cc1O3)N(c1ccccc1)c1cc(C(C)(C)C)cc3c1B4c1ccc(-c4ccccc4)cc1N3c1ccccc1)O2 ; CC(C)(C)c1ccc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)O4)cc(C(C)(C)C)c1] 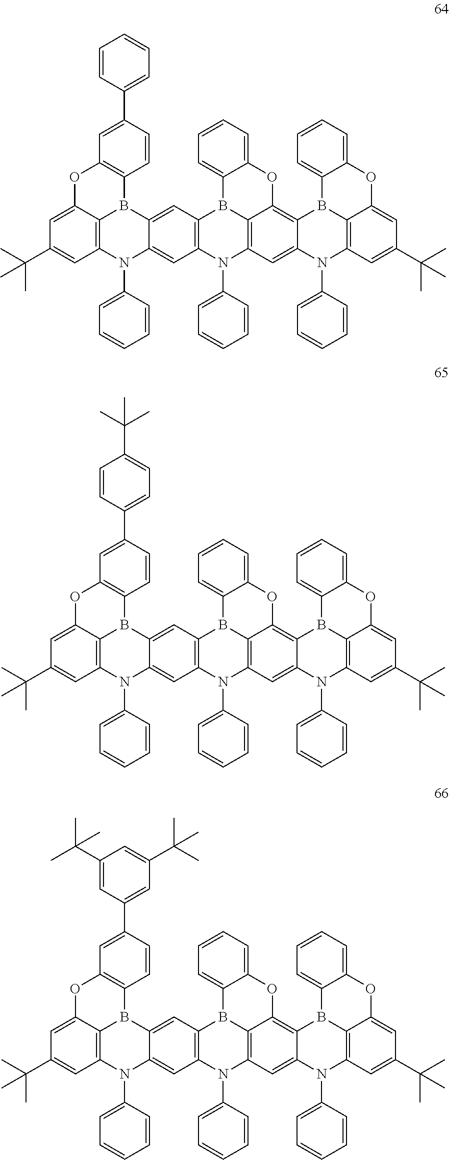 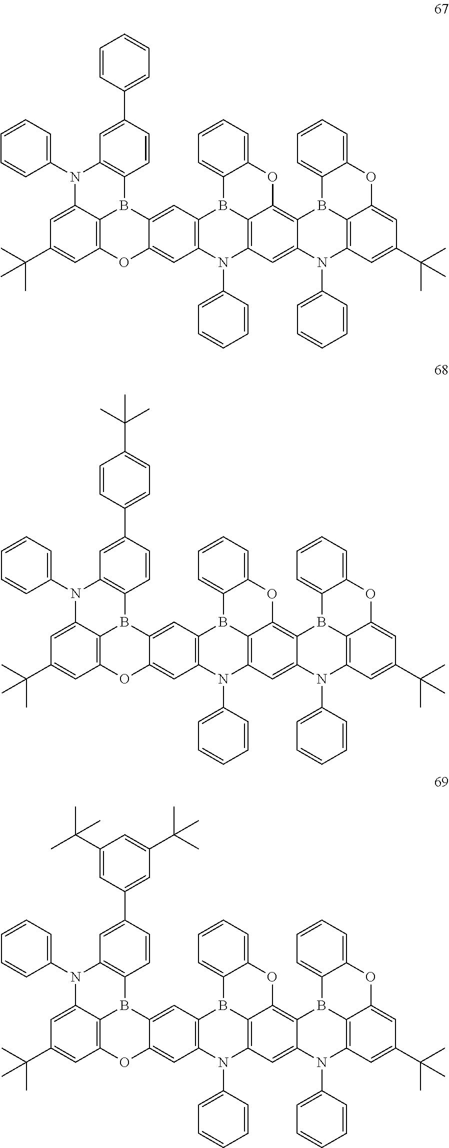 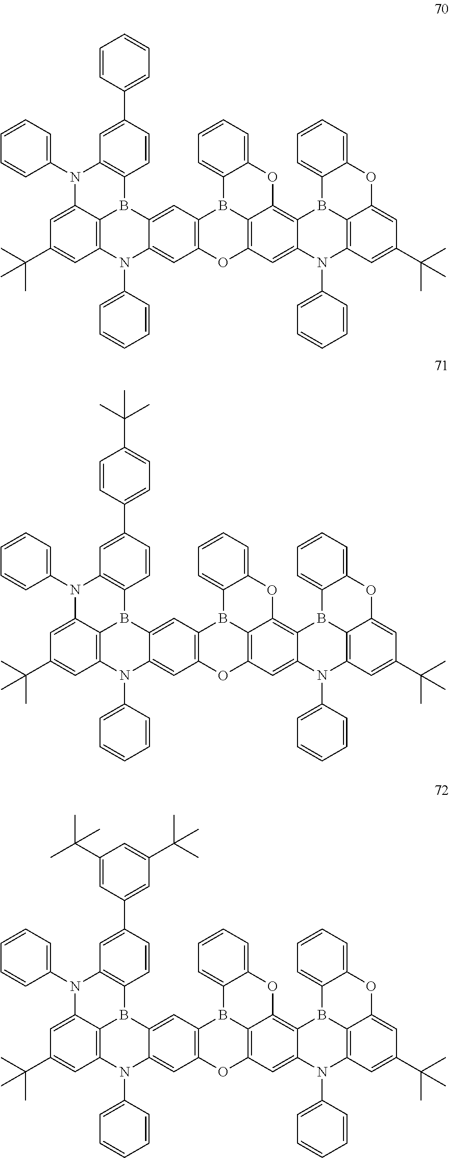 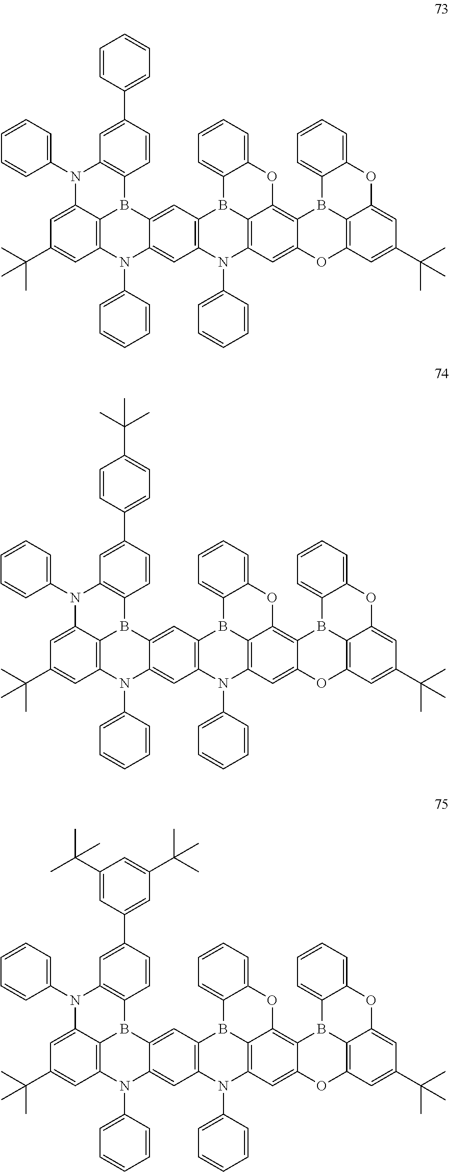 [SMILES: CC(C)(C)c1cc2c3c(c1)Oc1cc4c5c(c1B3c1ccccc1O2)Oc1ccccc1B5c1cc2c(cc1N4c1ccccc1)N(c1ccccc1)c1cc(C(C)(C)C)cc3c1B2c1ccc(-c2ccccc2)cc1N3c1ccccc1 ; CC(C)(C)c1ccc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3Oc3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3Oc3cc(C(C)(C)C)cc(c32)O4)cc(C(C)(C)C)c1] 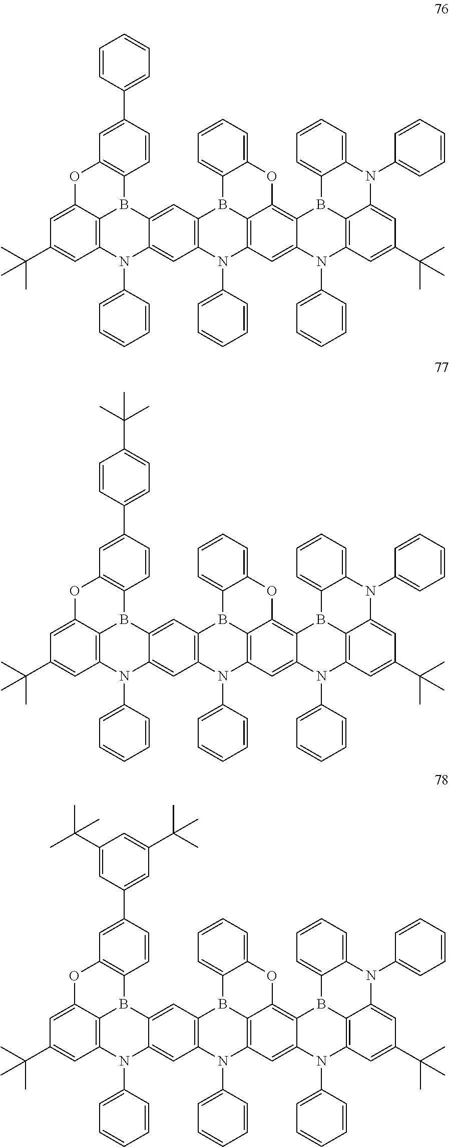 [SMILES: CC(C)(C)c1cc2c3c(c1)N(c1ccccc1)c1cc4c(cc1B3c1ccc(-c3ccccc3)cc1O2)B1c2ccccc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)Oc2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1] 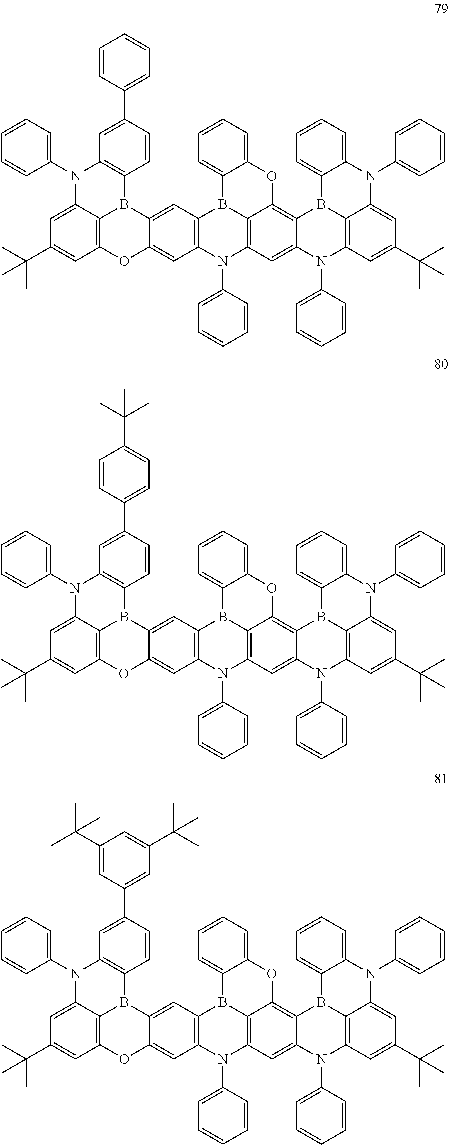 [SMILES: CC(C)(C)c1cc2c3c(c1)N(c1ccccc1)c1cc(-c4ccccc4)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)N2c1ccccc1 ; CC(C)(C)c1ccc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2O4)N(c2ccccc2)c2cc4c(c5c2B3c2ccccc2O5)B2c3ccccc3N(c3ccccc3)c3cc(C(C)(C)C)cc(c32)N4c2ccccc2)cc(C(C)(C)C)c1] 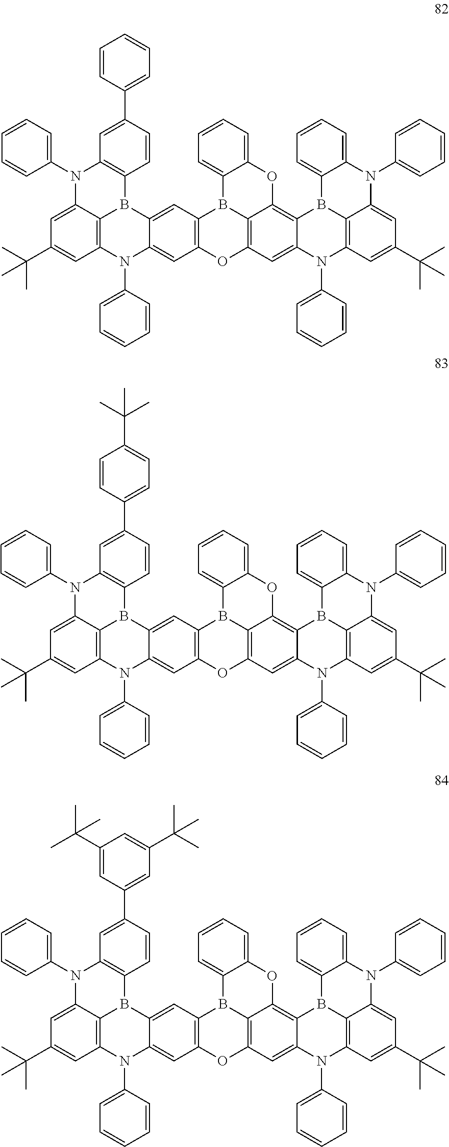 [SMILES: CC(C)(C)c1cc2c3c(c1)N(c1ccccc1)c1cc4c(cc1B3c1ccc(-c3ccccc3)cc1N2c1ccccc1)B1c2ccccc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc1 ; CC(C)(C)c1cc(-c2ccc3c(c2)N(c2ccccc2)c2cc(C(C)(C)C)cc4c2B3c2cc3c(cc2N4c2ccccc2)Oc2cc4c(c5c2B3c2ccccc2O5)B2c3ccccc3N(c3ccccc3)c3cc(C(C)(C)C)cc(c32)N4c2ccccc2)cc(C(C)(C)C)c1] 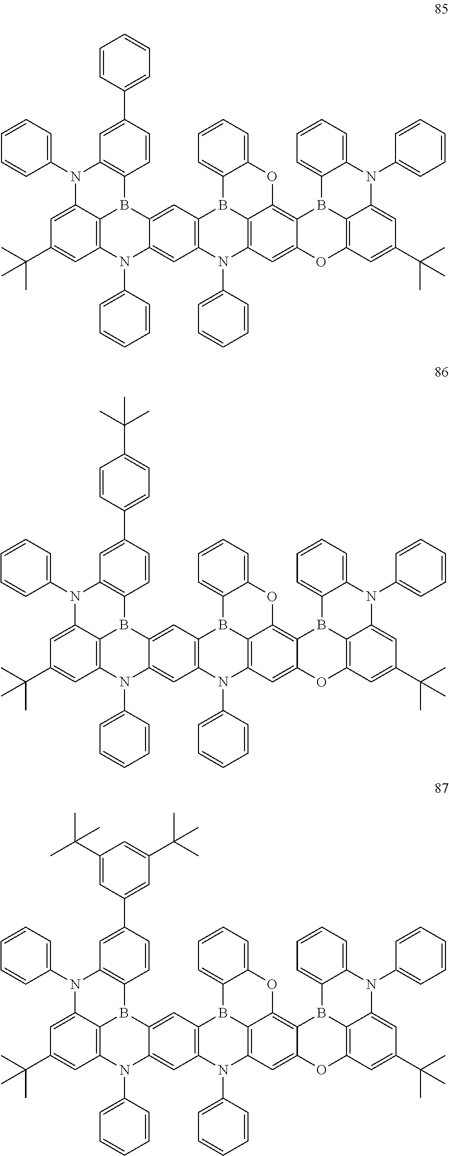 [SMILES: CC(C)(C)c1cc2c3c(c1)N(c1ccccc1)c1ccccc1B3c1c(cc3c4c1Oc1ccccc1B4c1cc4c(cc1N3c1ccccc1)N(c1ccccc1)c1cc(C(C)(C)C)cc3c1B4c1ccc(-c4ccccc4)cc1N3c1ccccc1)O2 ; CC(C)(C)c1ccc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc1 ; CC(C)(C)c1cc(-c2ccc3c(c2)N(c2ccccc2)c2cc(C(C)(C)C)cc4c2B3c2cc3c(cc2N4c2ccccc2)N(c2ccccc2)c2cc4c(c5c2B3c2ccccc2O5)B2c3ccccc3N(c3ccccc3)c3cc(C(C)(C)C)cc(c32)O4)cc(C(C)(C)C)c1] 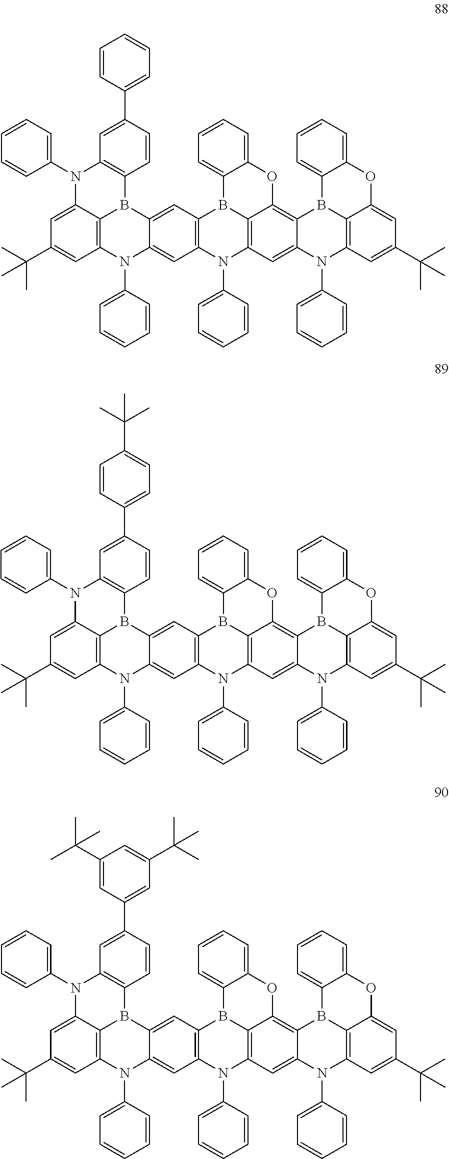 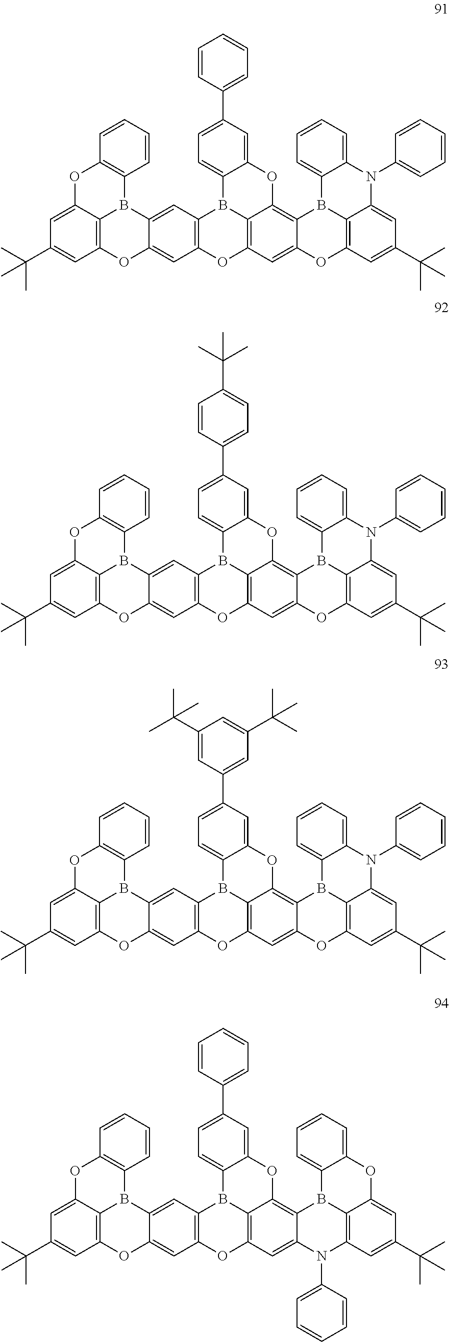 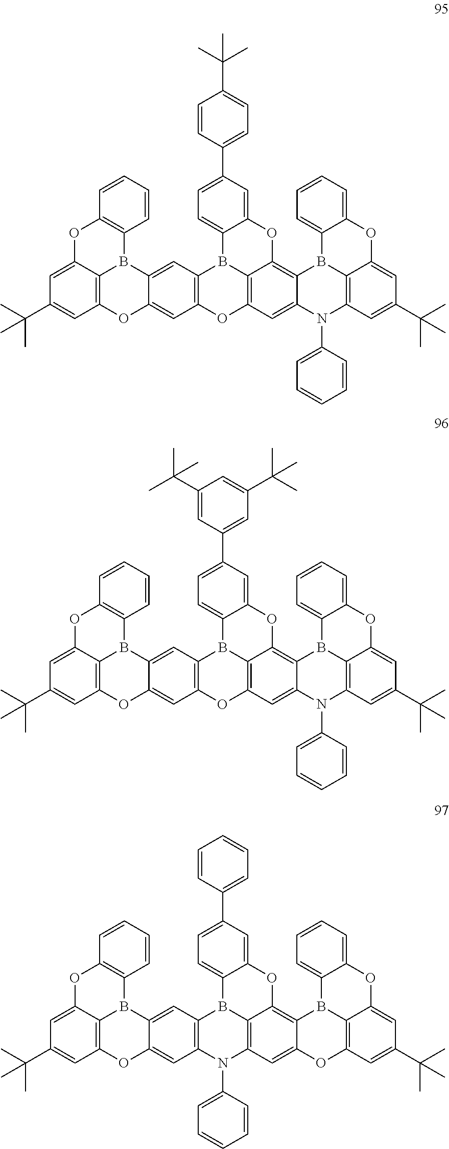 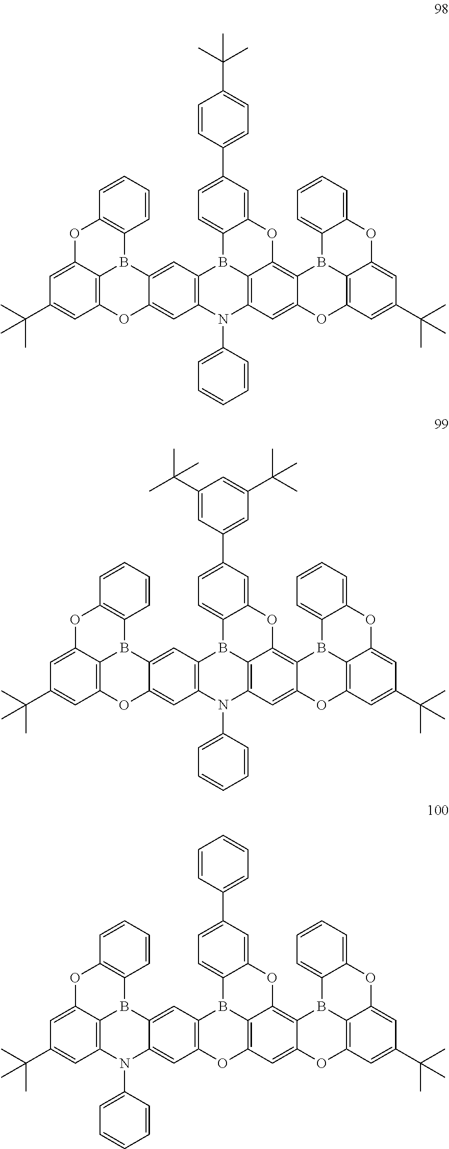 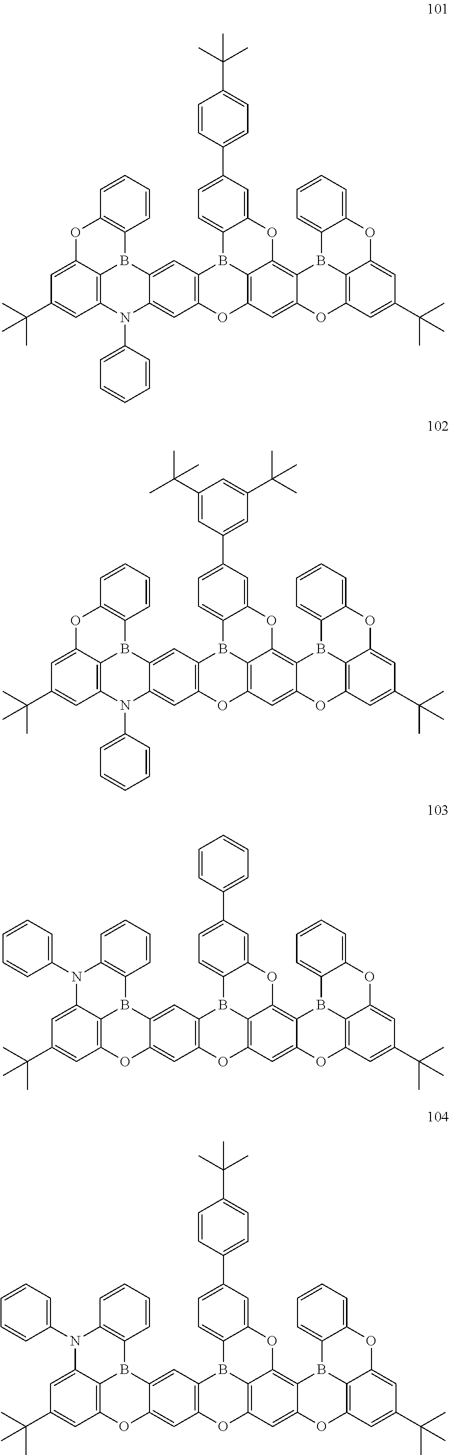 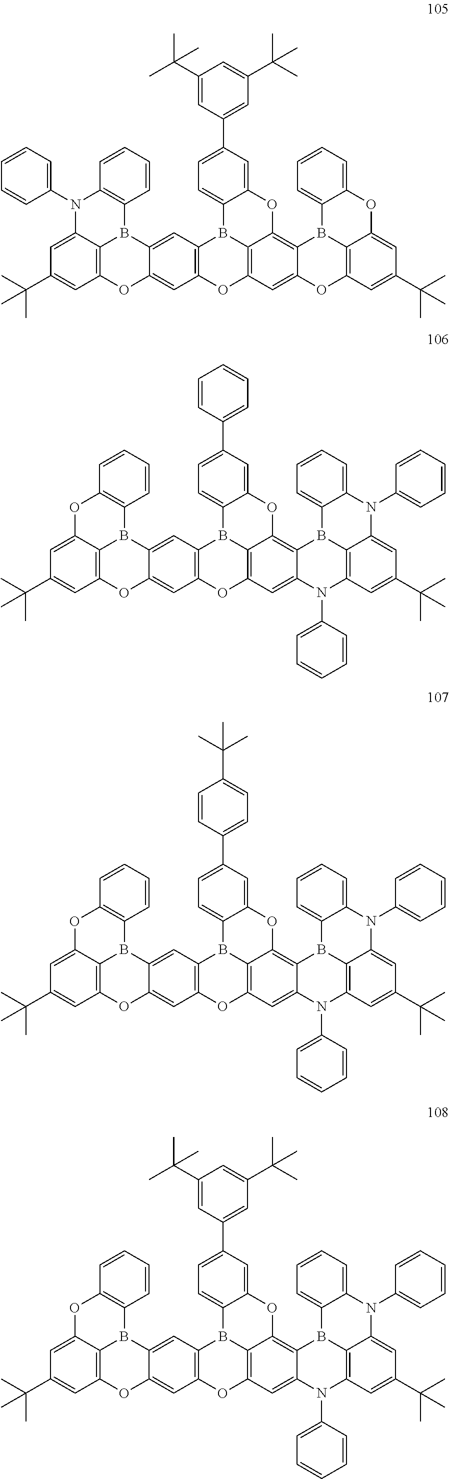 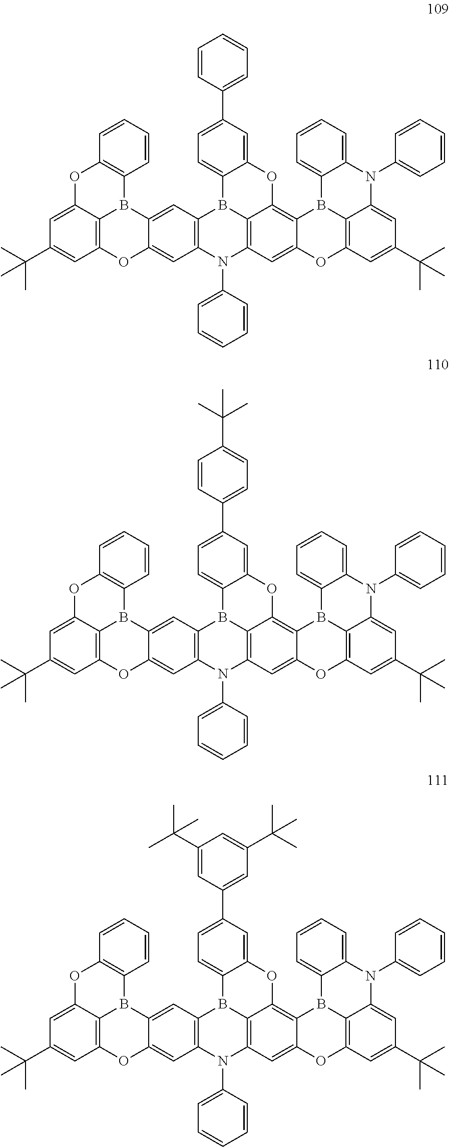 [SMILES: CC(C)(C)c1cc2c3c(c1)Oc1cc4c(cc1B3c1ccccc1O2)B1c2ccc(-c3ccccc3)cc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2c4c(cc5c2B3c2cc3c(cc2N5c2ccccc2)Oc2cc(C(C)(C)C)cc5c2B3c2ccccc2O5)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)Oc2cc(C(C)(C)C)cc5c2B3c2ccccc2O5)Oc2cc(C(C)(C)C)cc3c2B4c2ccccc2N3c2ccccc2)cc(C(C)(C)C)c1] 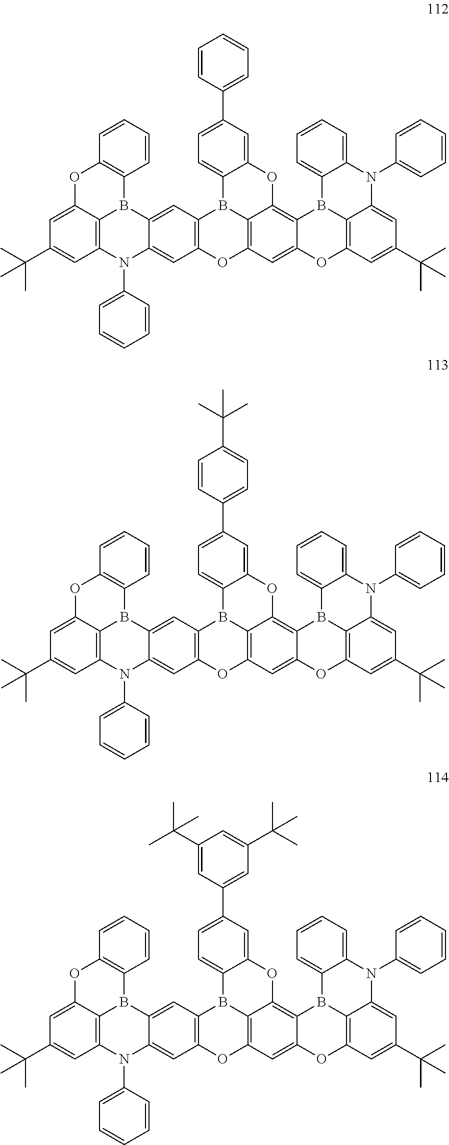 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)O1)O4 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3Oc3cc(C(C)(C)C)cc(c32)N5c2ccccc2)cc(C(C)(C)C)c1] 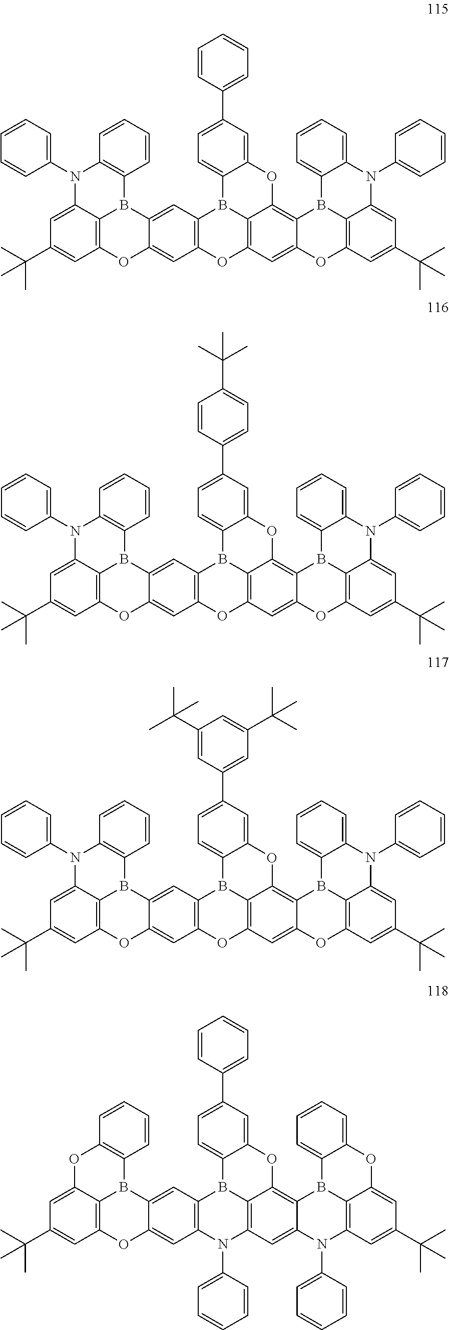 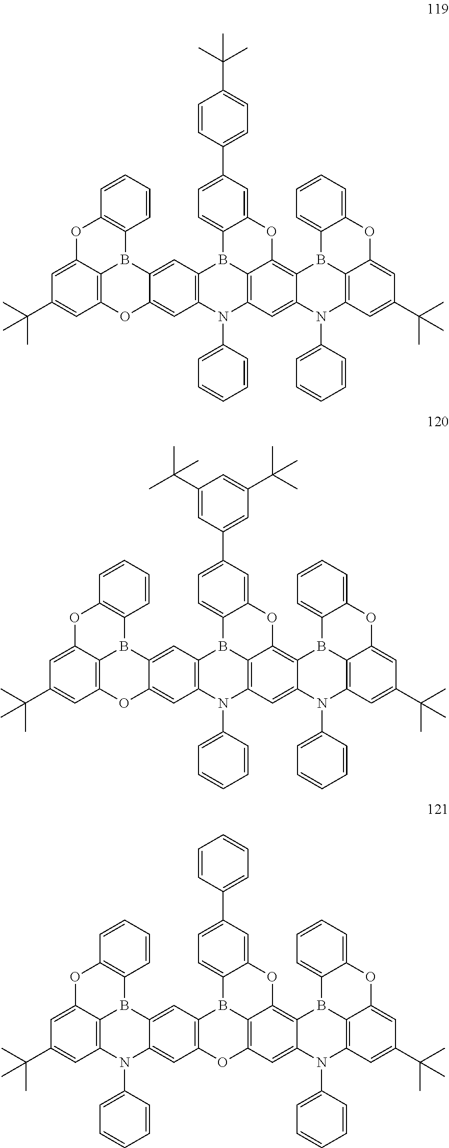 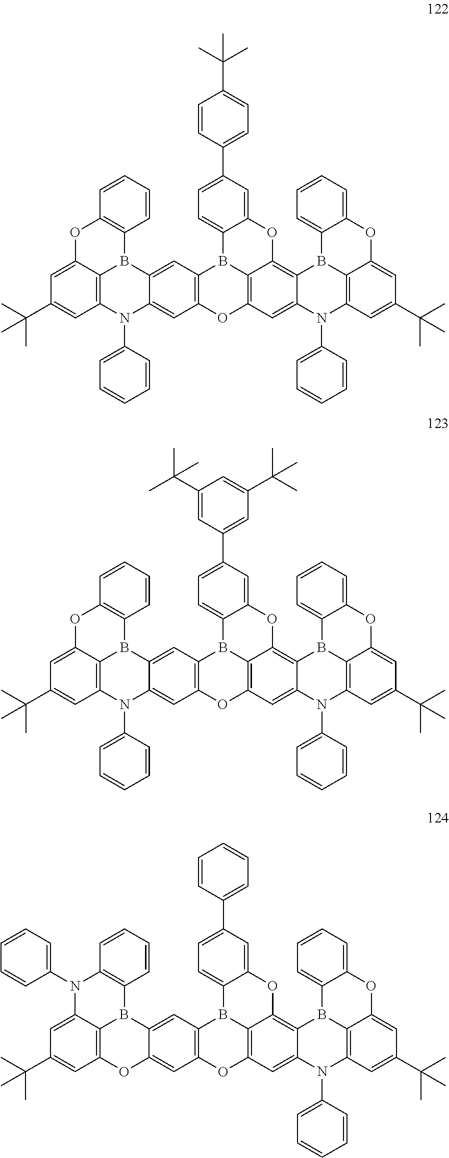 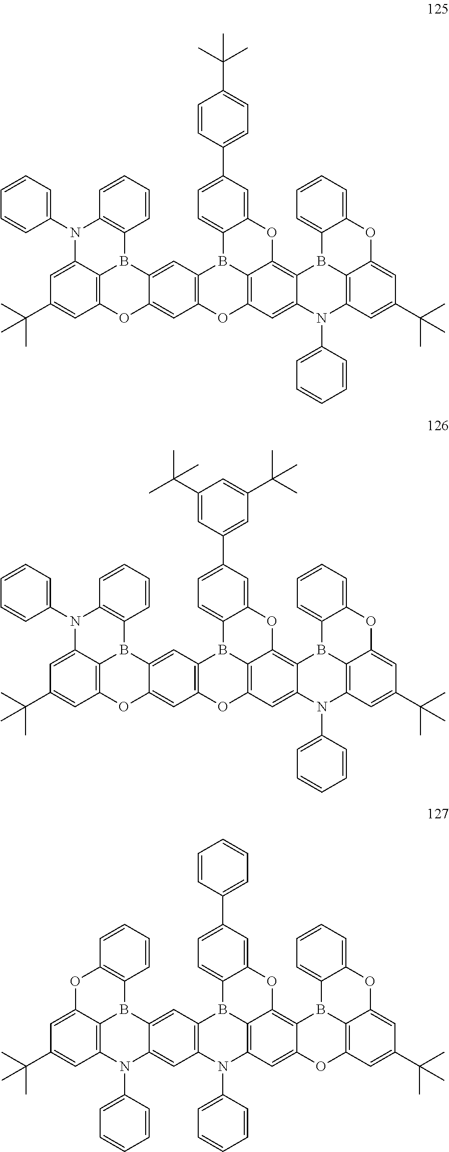 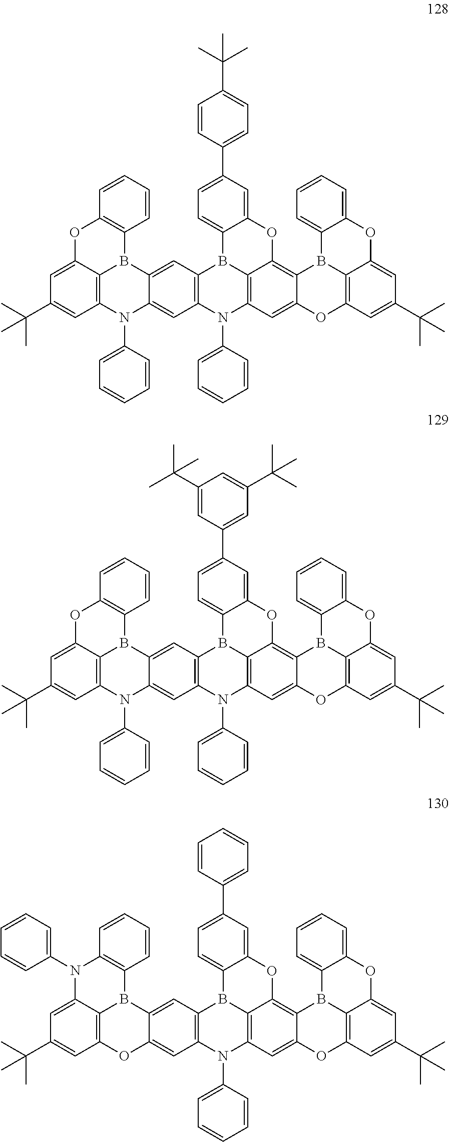 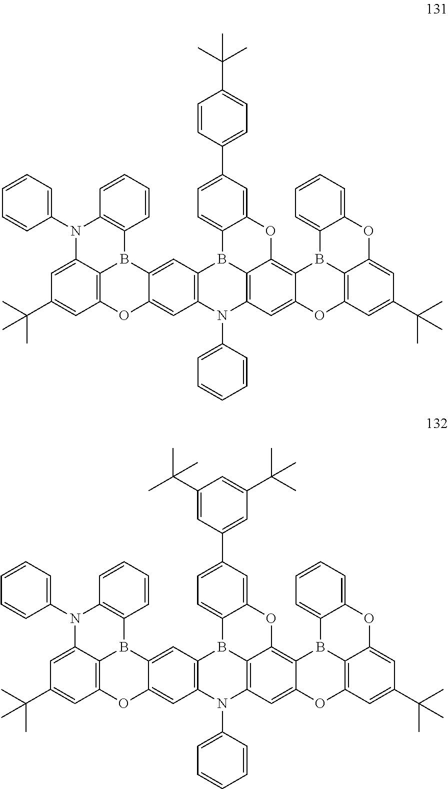 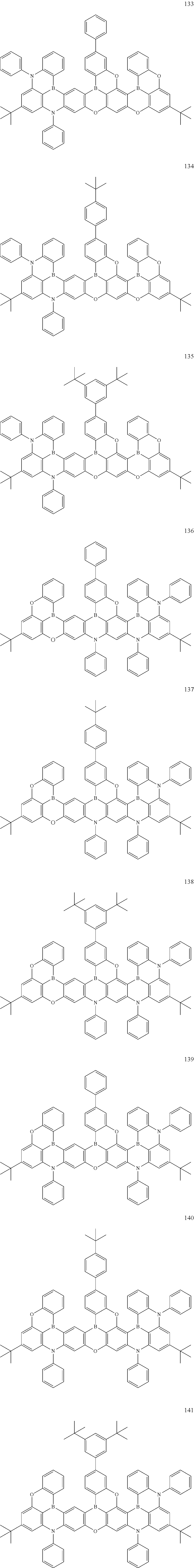 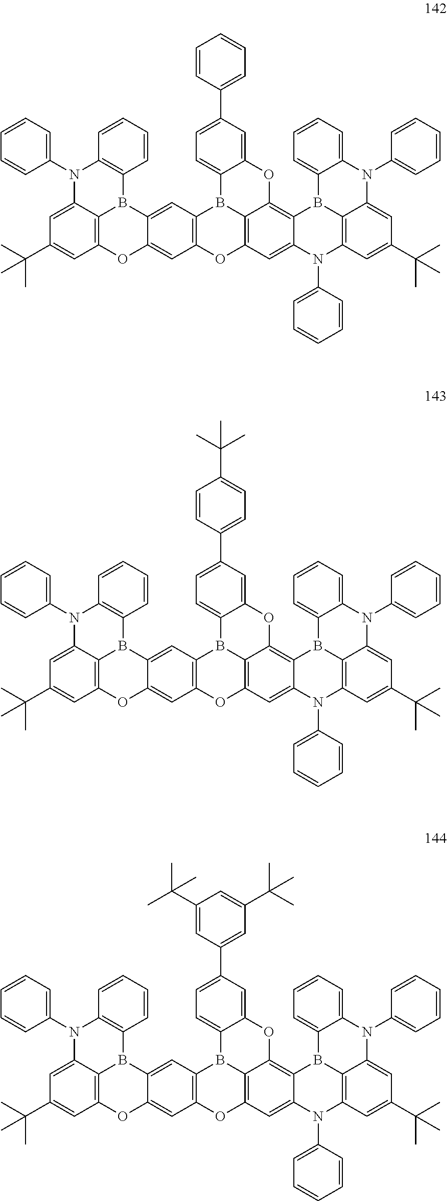 [SMILES: CC(C)(C)c1cc2c3c(c1)N(c1ccccc1)c1ccccc1B3c1cc3c(cc1O2)Oc1cc2c(c4c1B3c1ccc(-c3ccccc3)cc1O4)B1c3ccccc3N(c3ccccc3)c3cc(C(C)(C)C)cc(c31)N2c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)O5)cc(C(C)(C)C)c1] 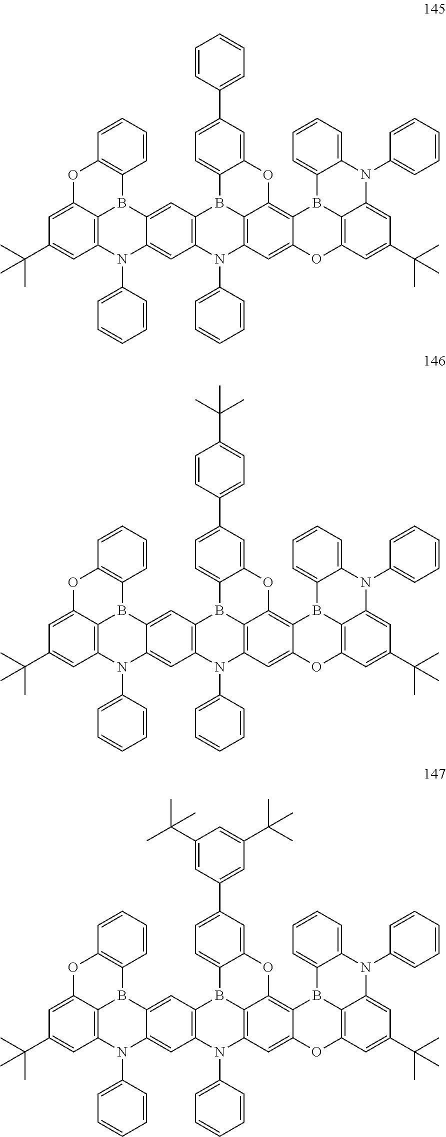 [SMILES: CC(C)(C)c1cc2c3c(c1)N(c1ccccc1)c1cc4c(cc1B3c1ccccc1O2)B1c2ccc(-c3ccccc3)cc2Oc2c3c(cc(c21)N4c1ccccc1)Oc1cc(C(C)(C)C)cc2c1B3c1ccccc1N2c1ccccc1 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2O5)Oc2cc(C(C)(C)C)cc3c2B4c2ccccc2N3c2ccccc2)cc(C(C)(C)C)c1] 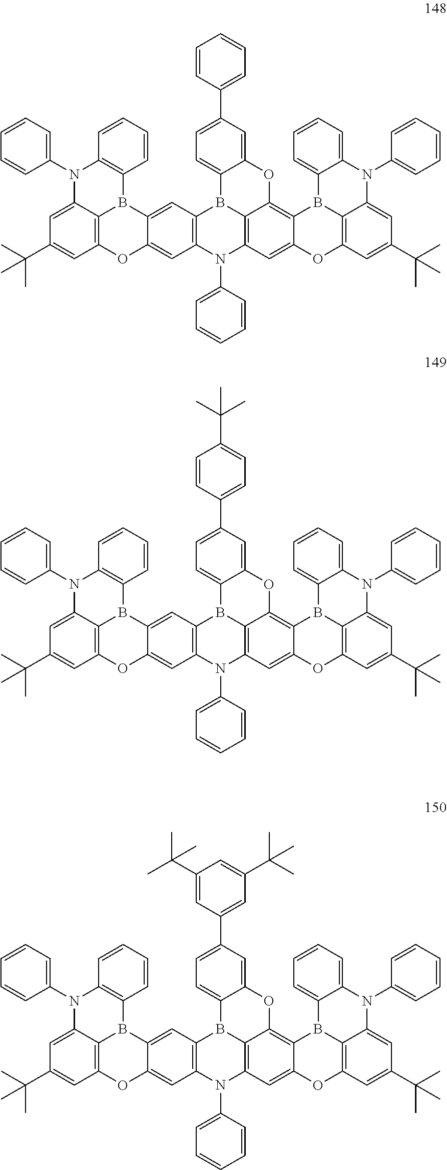 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)O2 ; CC(C)(C)c1ccc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)Oc2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1] 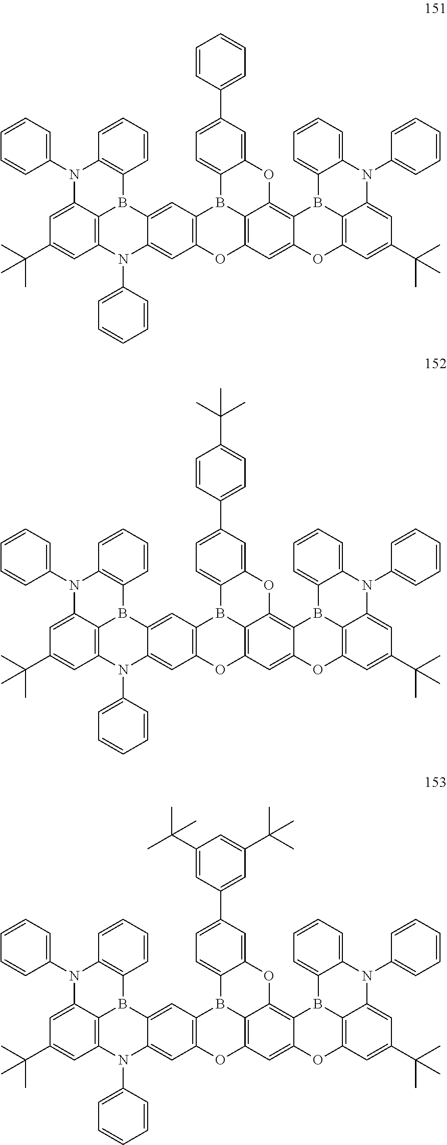 [SMILES: CC(C)(C)c1cc2c3c(c1)N(c1ccccc1)c1ccccc1B3c1c(cc3c4c1Oc1cc(-c5ccccc5)ccc1B4c1cc4c(cc1O3)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)O5)Oc2cc5c(cc2B34)B2c3ccccc3N(c3ccccc3)c3cc(C(C)(C)C)cc(c32)N5c2ccccc2)cc(C(C)(C)C)c1] 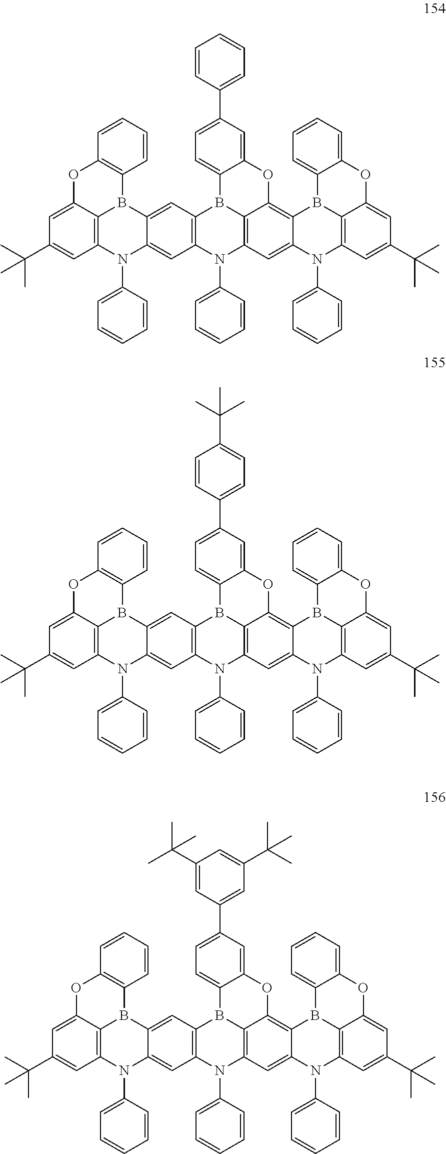 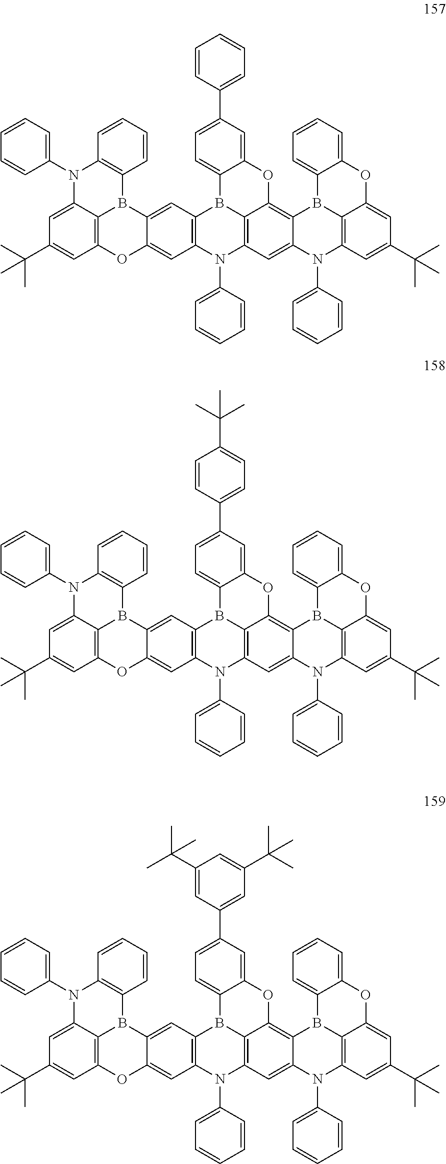 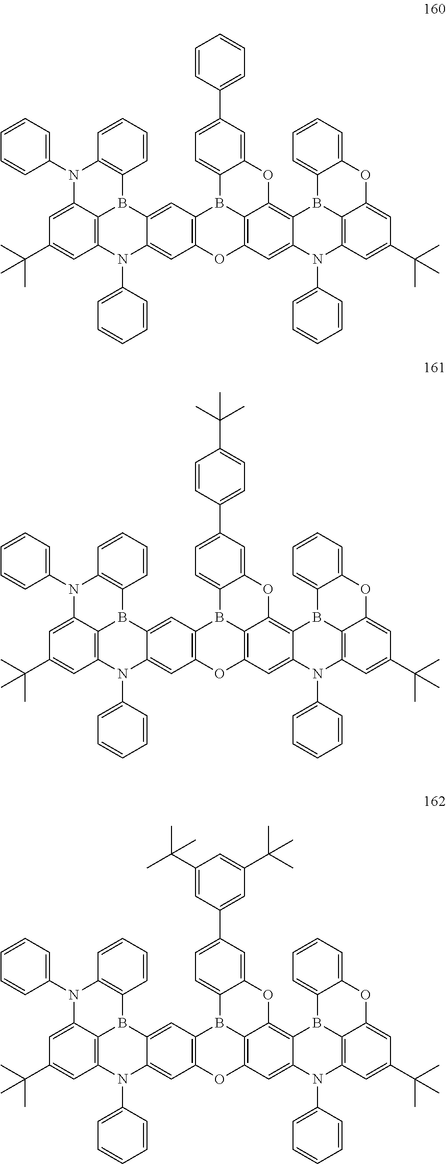 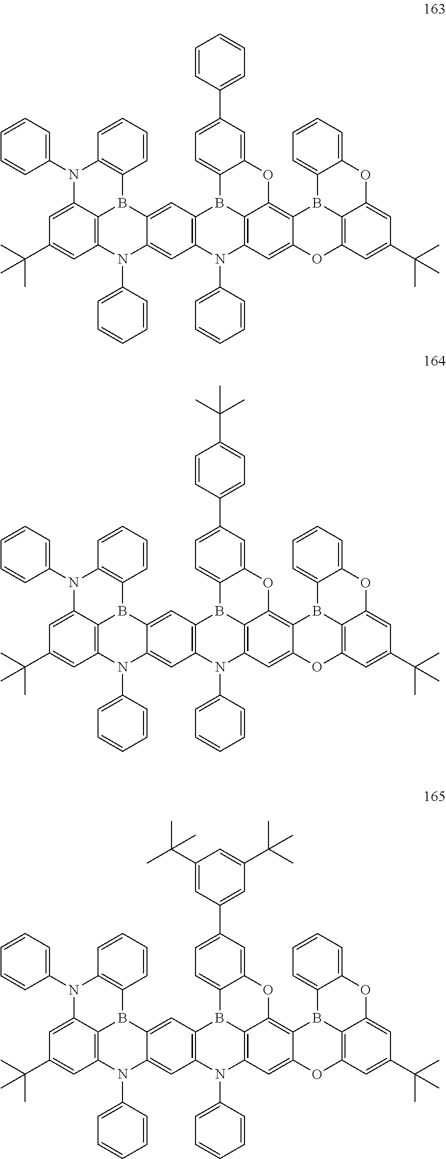 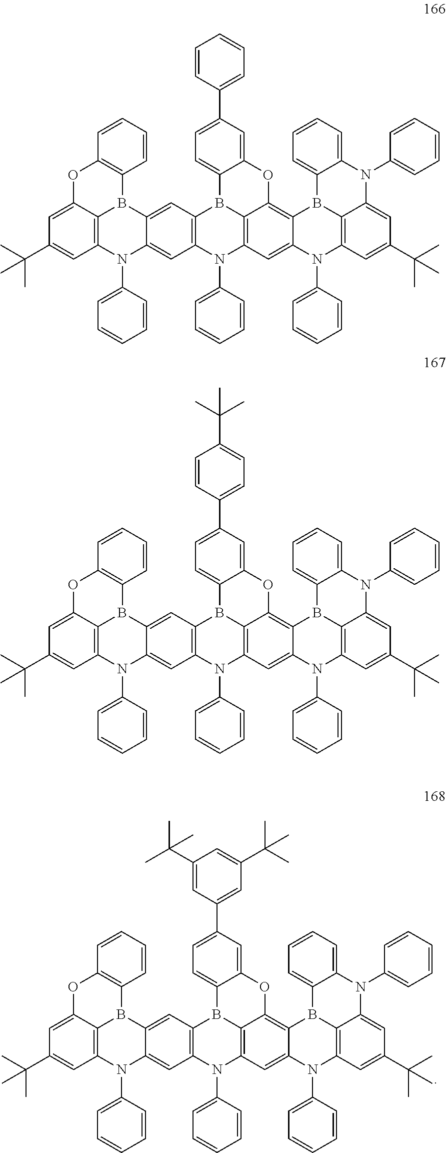 [SMILES: CC(C)(C)c1cc2c3c(c1)N(c1ccccc1)c1cc4c(cc1B3c1ccccc1O2)B1c2ccc(-c3ccccc3)cc2Oc2c1c(cc1c2B2c3ccccc3N(c3ccccc3)c3cc(C(C)(C)C)cc(c32)N1c1ccccc1)N4c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3Oc3cc(C(C)(C)C)cc(c32)N5c2ccccc2)cc(C(C)(C)C)c1] 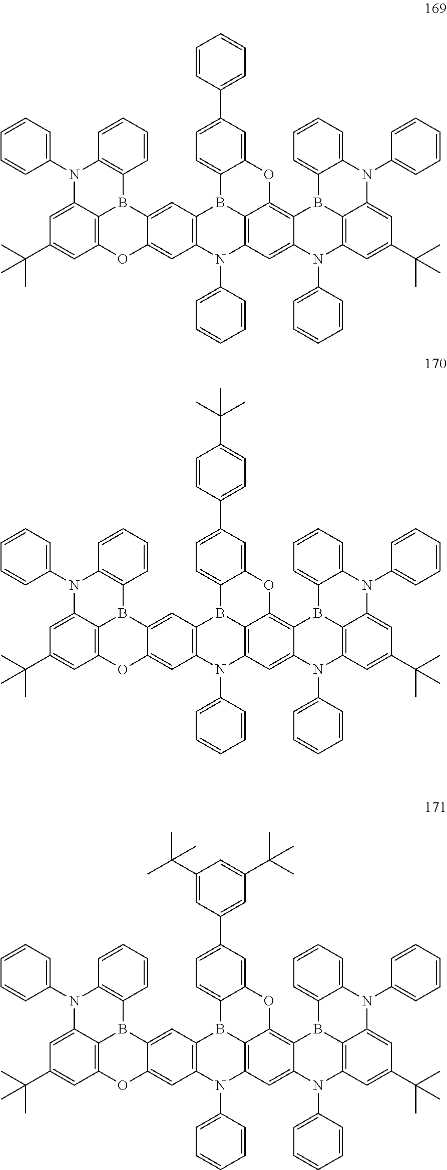 [SMILES: CC(C)(C)c1cc2c3c(c1)N(c1ccccc1)c1ccccc1B3c1cc3c(cc1O2)N(c1ccccc1)c1cc2c(c4c1B3c1ccc(-c3ccccc3)cc1O4)B1c3ccccc3N(c3ccccc3)c3cc(C(C)(C)C)cc(c31)N2c1ccccc1 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)N(c2ccccc2)c2cc5c(cc2B34)B2c3ccccc3N(c3ccccc3)c3cc(C(C)(C)C)cc(c32)O5)cc(C(C)(C)C)c1] 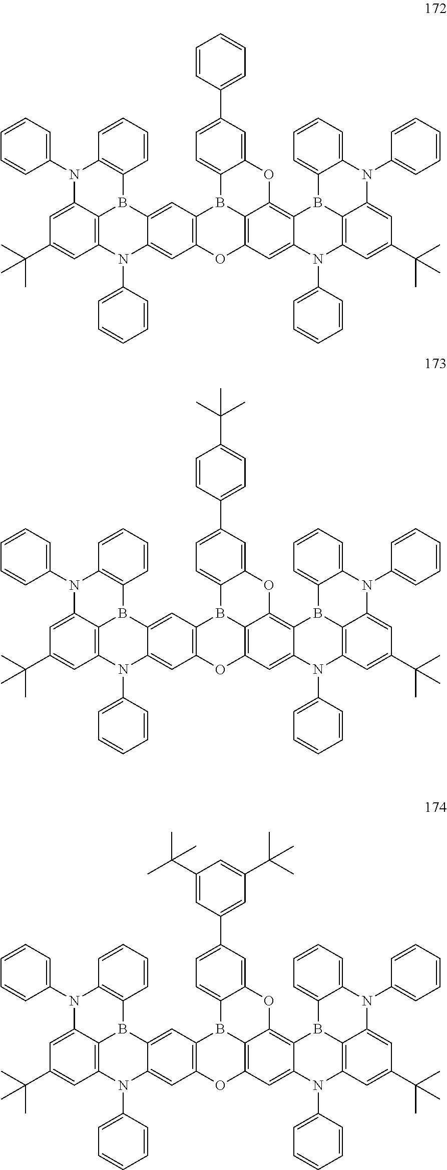 [SMILES: CC(C)(C)c1cc2c3c(c1)N(c1ccccc1)c1cc4c(cc1B3c1ccccc1N2c1ccccc1)B1c2ccc(-c3ccccc3)cc2Oc2c1c(cc1c2B2c3ccccc3N(c3ccccc3)c3cc(C(C)(C)C)cc(c32)N1c1ccccc1)O4 ; CC(C)(C)c1ccc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc1 ; CC(C)(C)c1cc(-c2ccc3c(c2)Oc2c4c(cc5c2B2c6ccccc6N(c6ccccc6)c6cc(C(C)(C)C)cc(c62)N5c2ccccc2)Oc2cc5c(cc2B34)B2c3ccccc3N(c3ccccc3)c3cc(C(C)(C)C)cc(c32)N5c2ccccc2)cc(C(C)(C)C)c1] 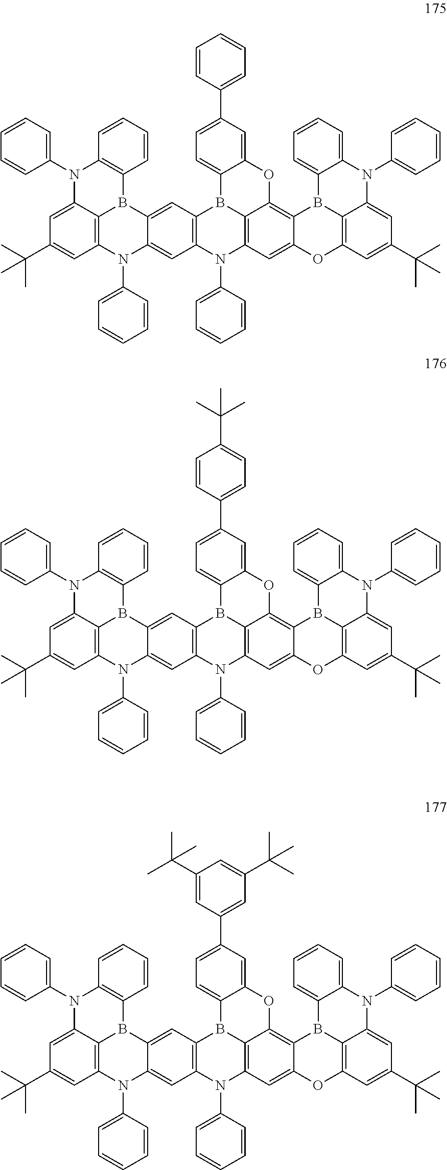 [SMILES: CC(C)(C)c1cc2c3c(c1)N(c1ccccc1)c1ccccc1B3c1c(cc3c4c1Oc1cc(-c5ccccc5)ccc1B4c1cc4c(cc1N3c1ccccc1)N(c1ccccc1)c1cc(C(C)(C)C)cc3c1B4c1ccccc1N3c1ccccc1)O2 ; CC(C)(C)c1ccc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc1 ; CC(C)(C)c1cc(-c2ccc3c(c2)Oc2c4c(cc5c2B3c2cc3c(cc2N5c2ccccc2)N(c2ccccc2)c2cc(C(C)(C)C)cc5c2B3c2ccccc2N5c2ccccc2)Oc2cc(C(C)(C)C)cc3c2B4c2ccccc2N3c2ccccc2)cc(C(C)(C)C)c1] 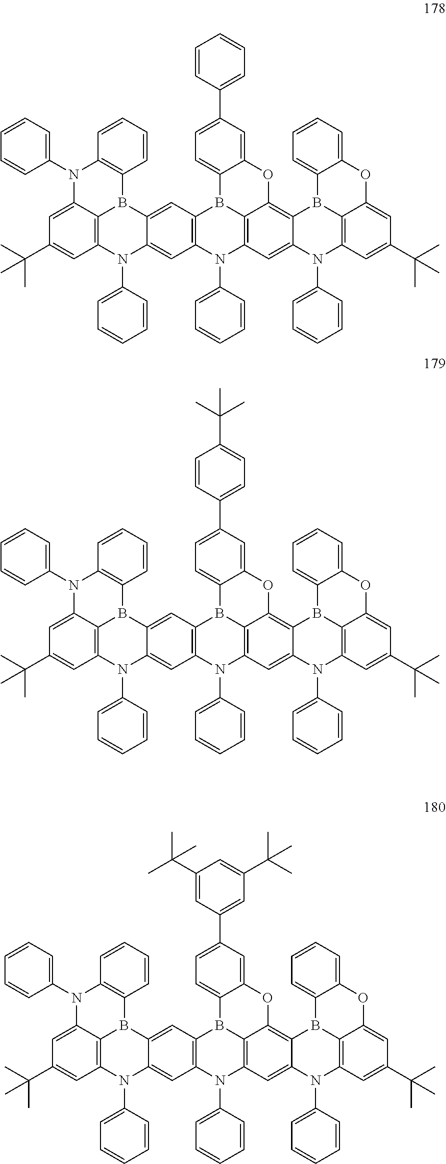 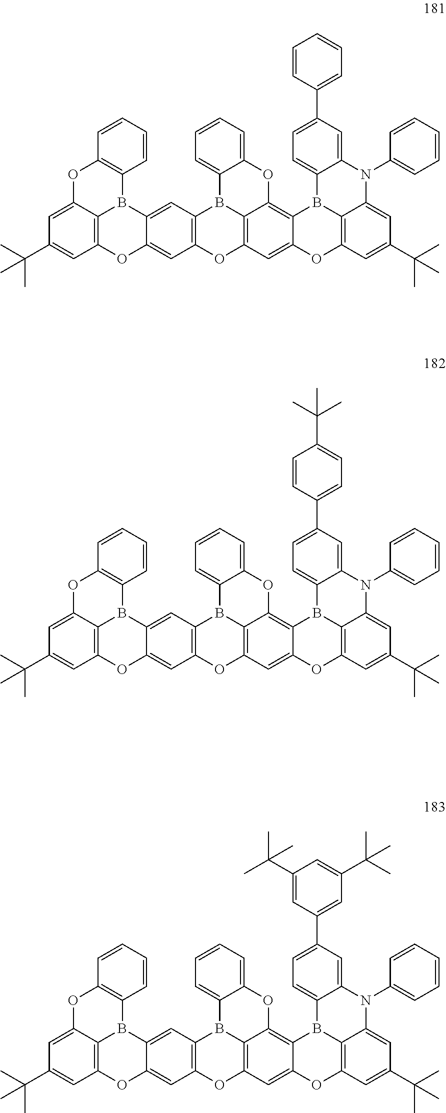 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)O4)cc(C(C)(C)C)c1] 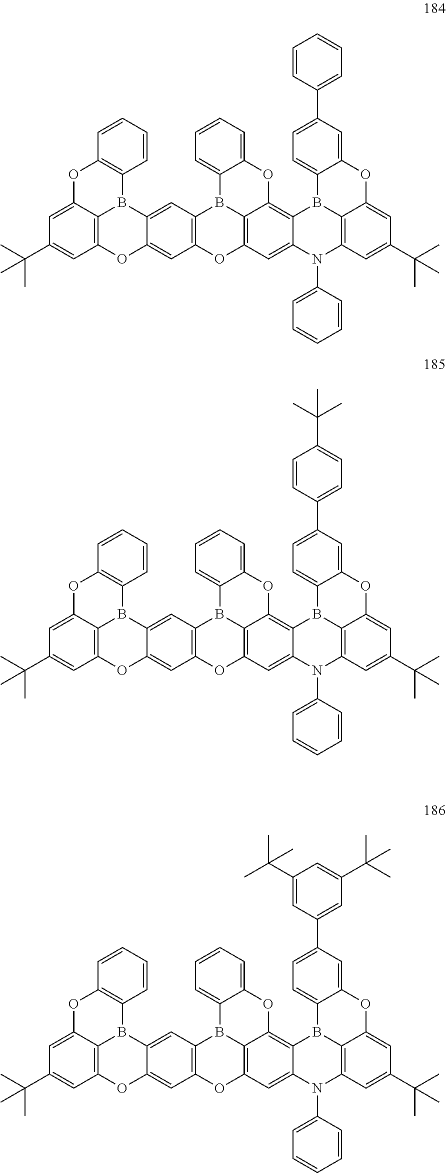 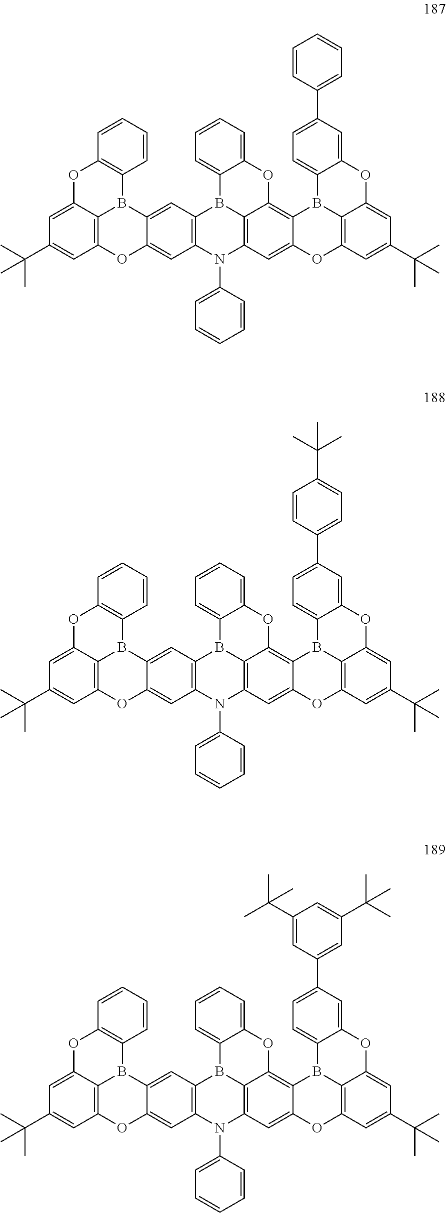 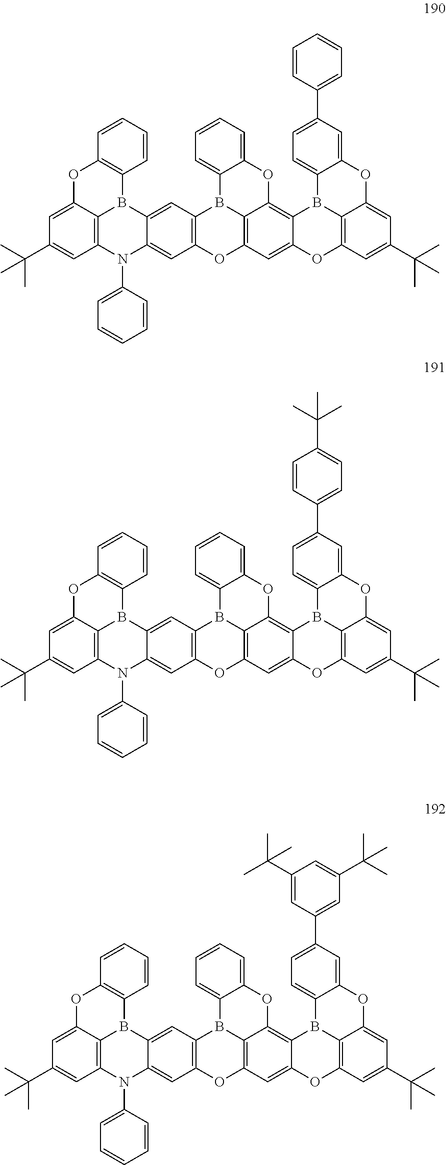 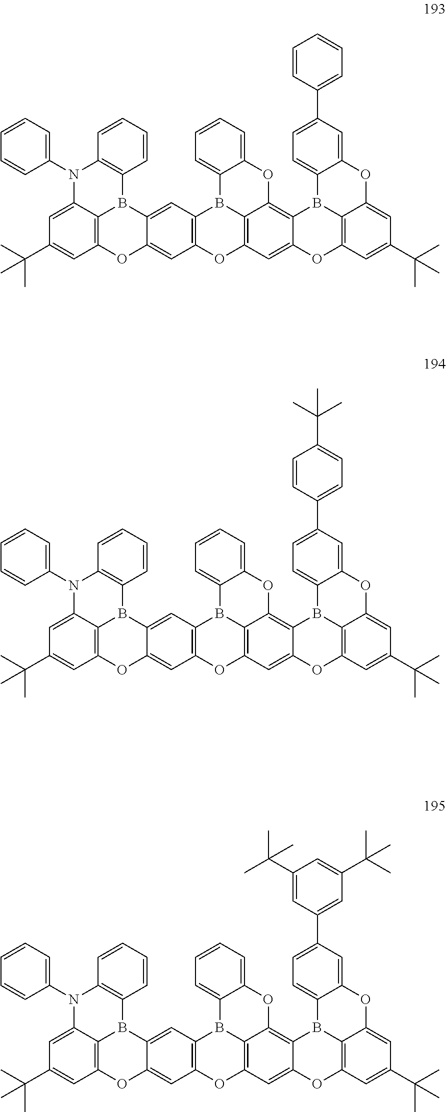 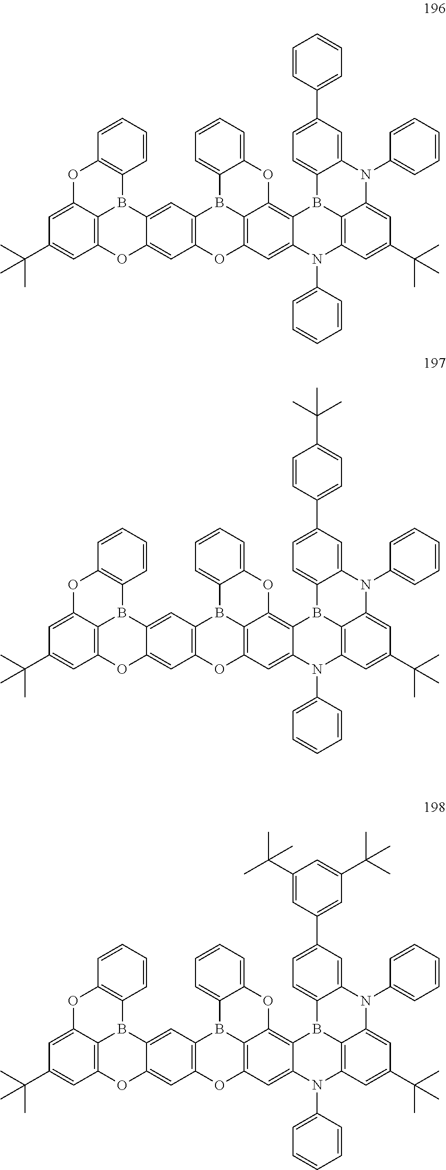 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)N1c1ccccc1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2O3)N4c2ccccc2)cc(C(C)(C)C)c1] 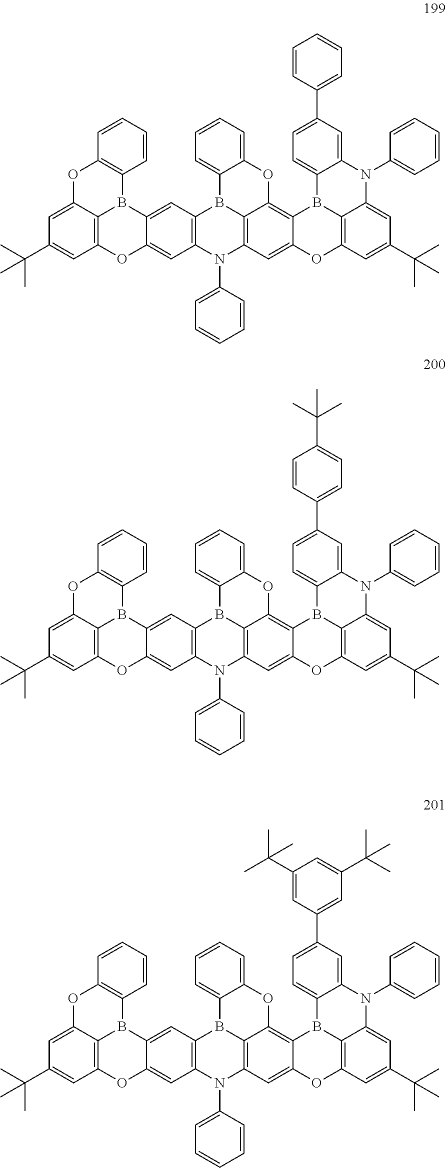 [SMILES: CC(C)(C)c1cc2c3c(c1)Oc1cc4c(cc1B3c1ccccc1O2)B1c2ccccc2Oc2c3c(cc(c21)N4c1ccccc1)Oc1cc(C(C)(C)C)cc2c1B3c1ccc(-c3ccccc3)cc1N2c1ccccc1 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2O3)O4)cc(C(C)(C)C)c1] 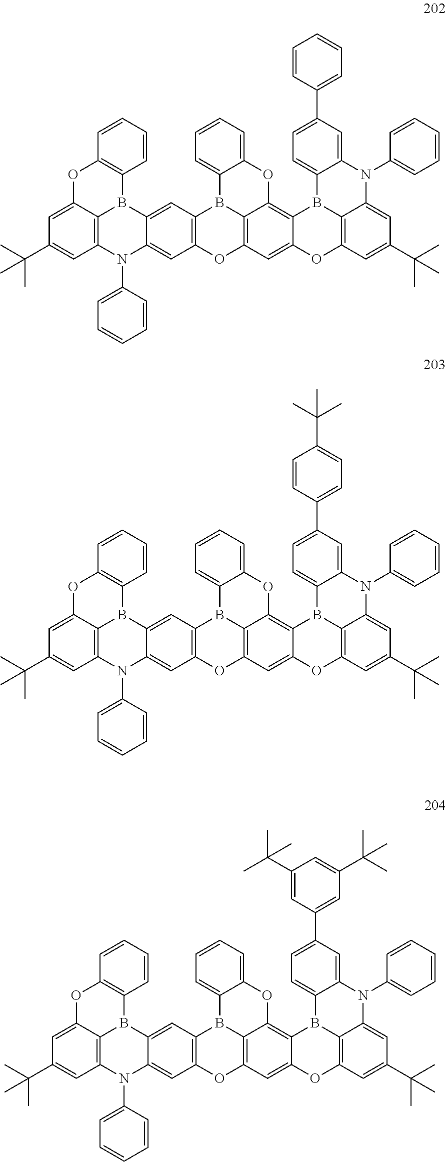 [SMILES: CC(C)(C)c1cc2c3c(c1)N(c1ccccc1)c1cc4c(cc1B3c1ccccc1O2)B1c2ccccc2Oc2c1c(cc1c2B2c3ccc(-c5ccccc5)cc3N(c3ccccc3)c3cc(C(C)(C)C)cc(c32)O1)O4 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2O3)O4)cc(C(C)(C)C)c1] 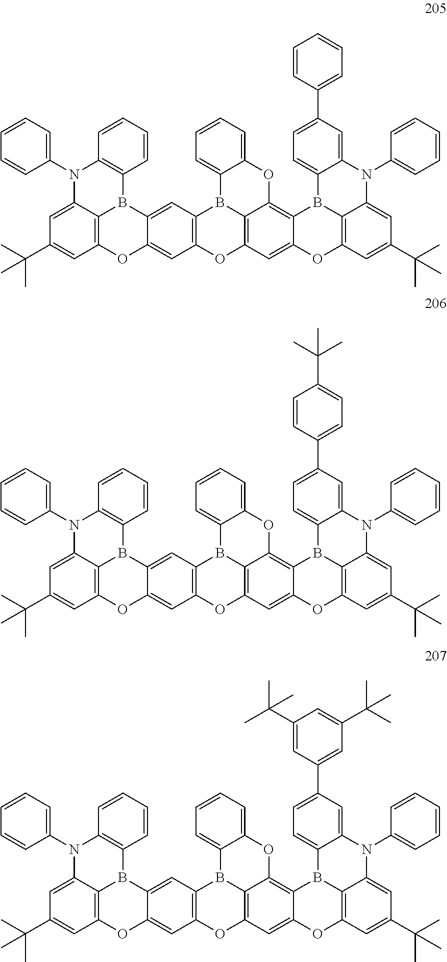 [SMILES: CC(C)(C)c1cc2c3c(c1)N(c1ccccc1)c1ccccc1B3c1cc3c(cc1O2)Oc1cc2c(c4c1B3c1ccccc1O4)B1c3ccc(-c4ccccc4)cc3N(c3ccccc3)c3cc(C(C)(C)C)cc(c31)O2 ; CC(C)(C)c1ccc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc1 ; CC(C)(C)c1cc(-c2ccc3c(c2)N(c2ccccc2)c2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)O4)cc(C(C)(C)C)c1] 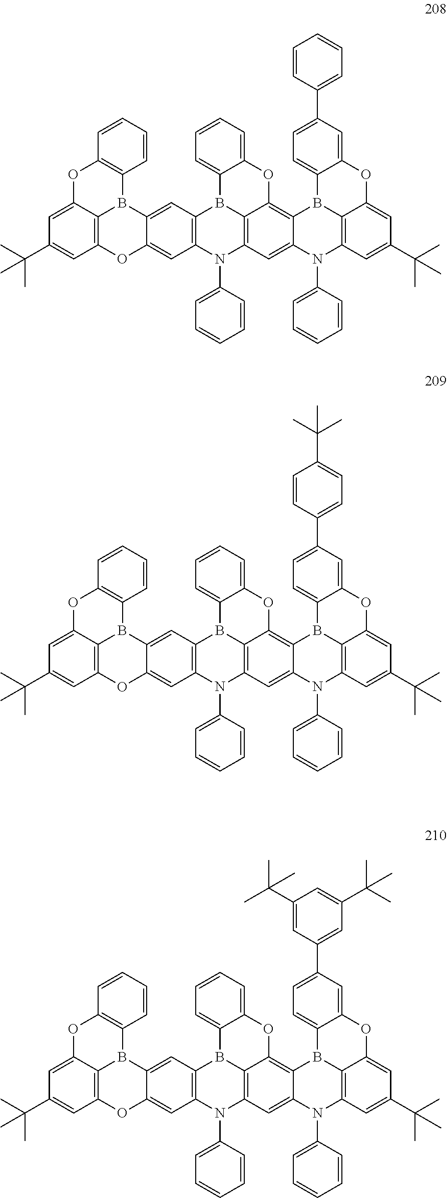 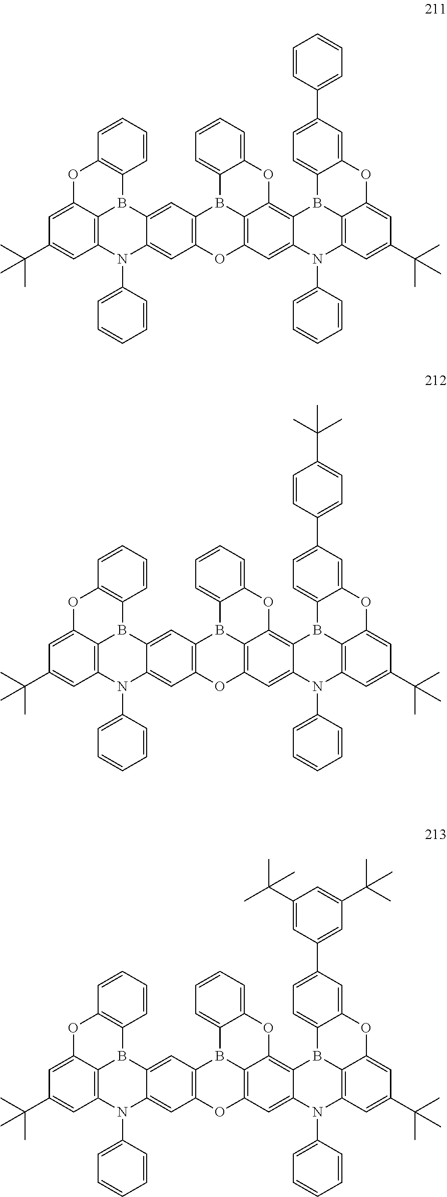 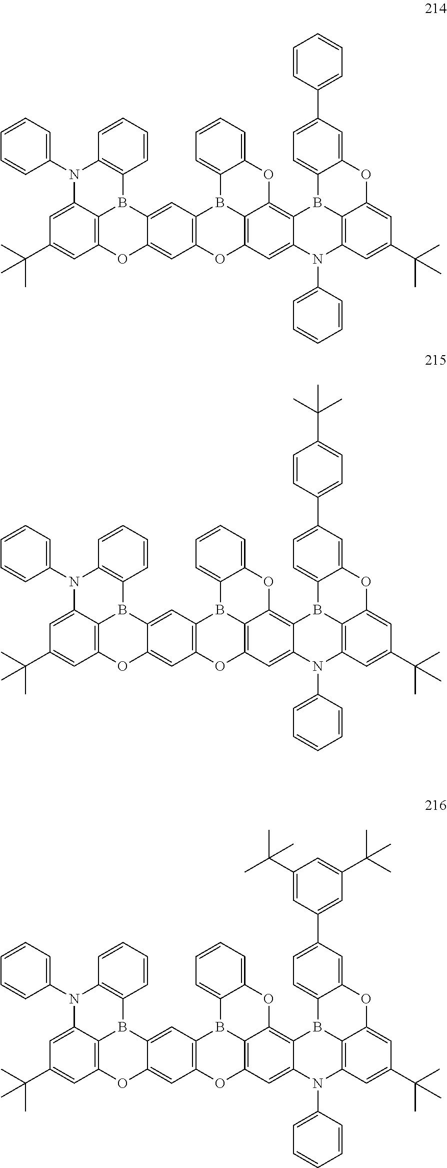 [SMILES: CC(C)(C)c1cc2c3c(c1)N(c1ccccc1)c1ccccc1B3c1cc3c(cc1O2)Oc1cc2c(c4c1B3c1ccccc1O4)B1c3ccc(-c4ccccc4)cc3Oc3cc(C(C)(C)C)cc(c31)N2c1ccccc1 ; CC(C)(C)c1ccc(-c2ccc3c(c2)Oc2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)N4c2ccccc2)cc1 ; CC(C)(C)c1cc(-c2ccc3c(c2)Oc2cc(C(C)(C)C)cc4c2B3c2c(cc3c5c2Oc2ccccc2B5c2cc5c(cc2O3)Oc2cc(C(C)(C)C)cc3c2B5c2ccccc2N3c2ccccc2)N4c2ccccc2)cc(C(C)(C)C)c1] 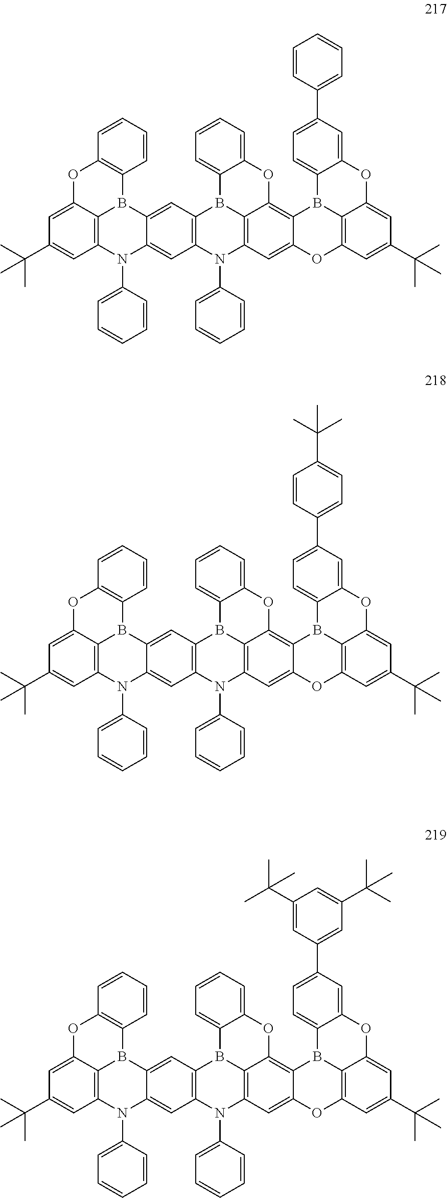 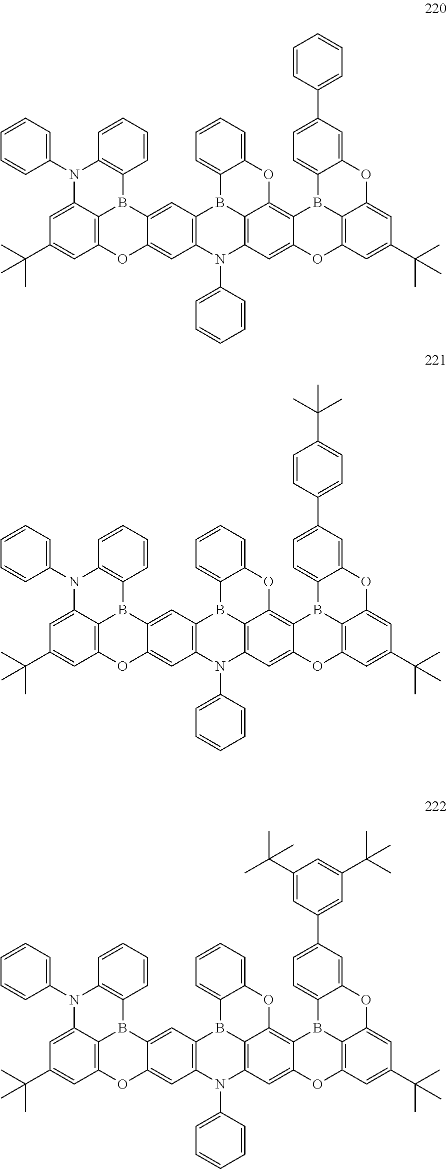 [SMILES: CC(C)(C)c1cc2c3c(c1)Oc1cc4c5c(c1B3c1ccc(-c3ccccc3)cc1O2)Oc1ccccc1B5c1cc2c(cc1N4c1ccccc1)Oc1cc(C(C)(C)C)cc3c1B2c1ccccc1N3c1ccccc1 ; CC(C)(C)c1ccc(-c2ccc3c(c2)Oc2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2N3c2ccccc2)O4)cc1 ; CC(C)(C)c1cc(-c2ccc3c(c2)Oc2cc(C(C)(C)C)cc4c2B3c2c(cc3c5c2Oc2ccccc2B5c2cc5c(cc2N3c2ccccc2)Oc2cc(C(C)(C)C)cc3c2B5c2ccccc2N3c2ccccc2)O4)cc(C(C)(C)C)c1] 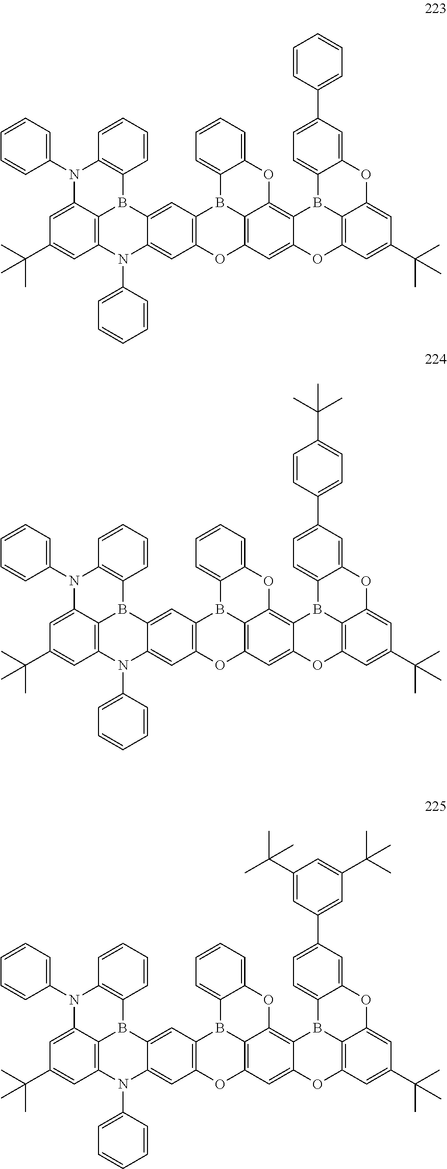 [SMILES: CC(C)(C)c1cc2c3c(c1)Oc1cc4c5c(c1B3c1ccc(-c3ccccc3)cc1O2)Oc1ccccc1B5c1cc2c(cc1O4)N(c1ccccc1)c1cc(C(C)(C)C)cc3c1B2c1ccccc1N3c1ccccc1 ; CC(C)(C)c1ccc(-c2ccc3c(c2)Oc2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2N3c2ccccc2)O4)cc1 ; CC(C)(C)c1cc(-c2ccc3c(c2)Oc2cc(C(C)(C)C)cc4c2B3c2c(cc3c5c2Oc2ccccc2B5c2cc5c(cc2O3)N(c2ccccc2)c2cc(C(C)(C)C)cc3c2B5c2ccccc2N3c2ccccc2)O4)cc(C(C)(C)C)c1] 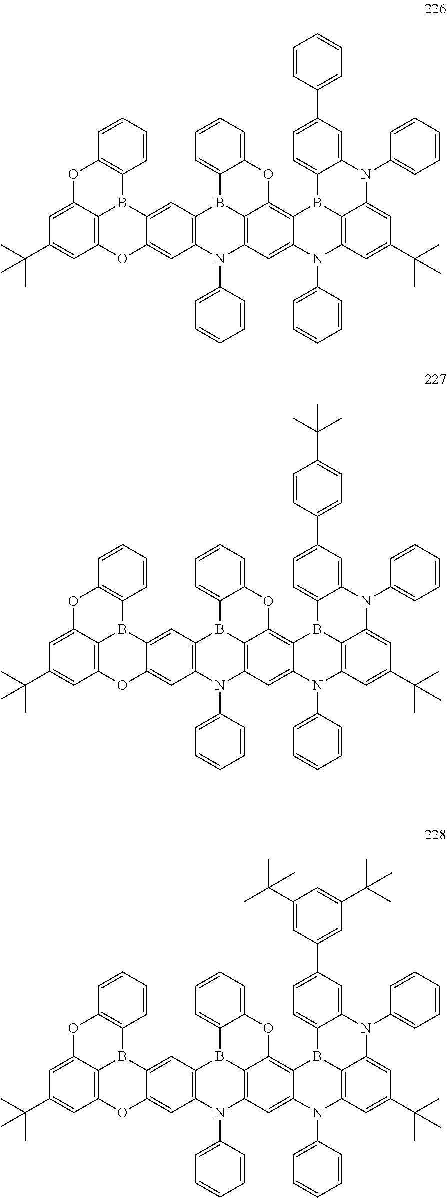 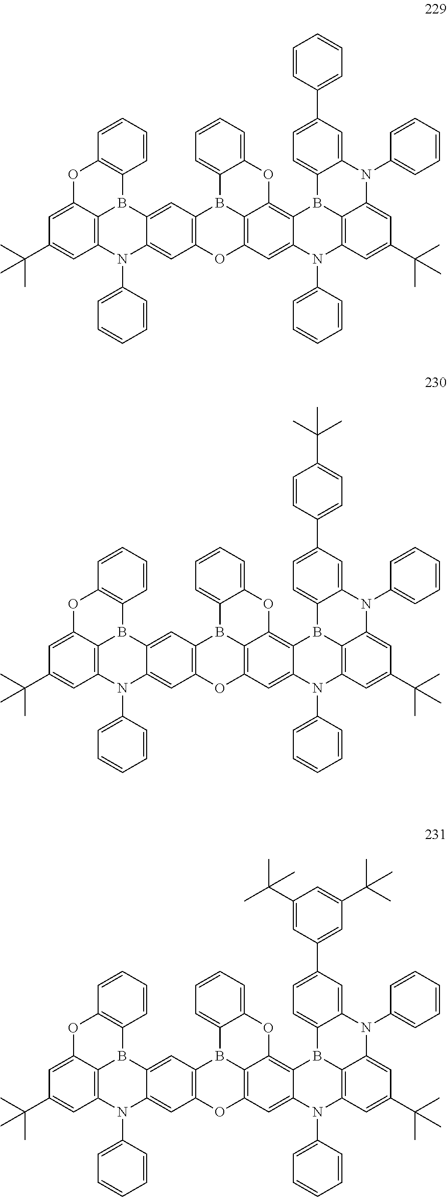 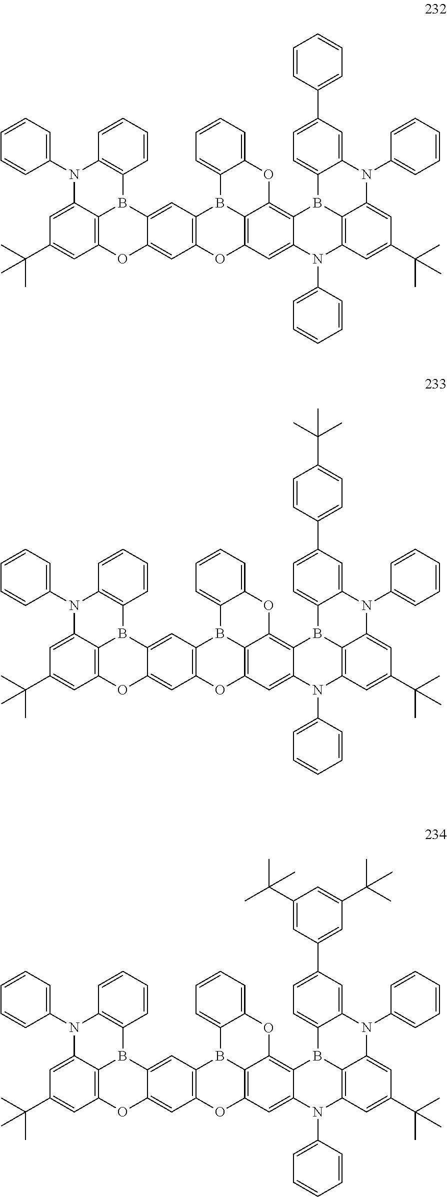 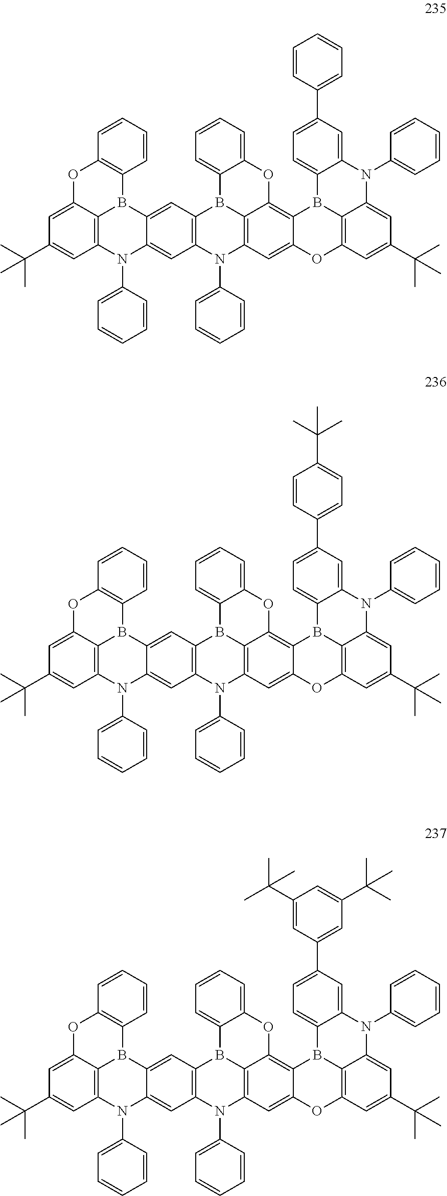 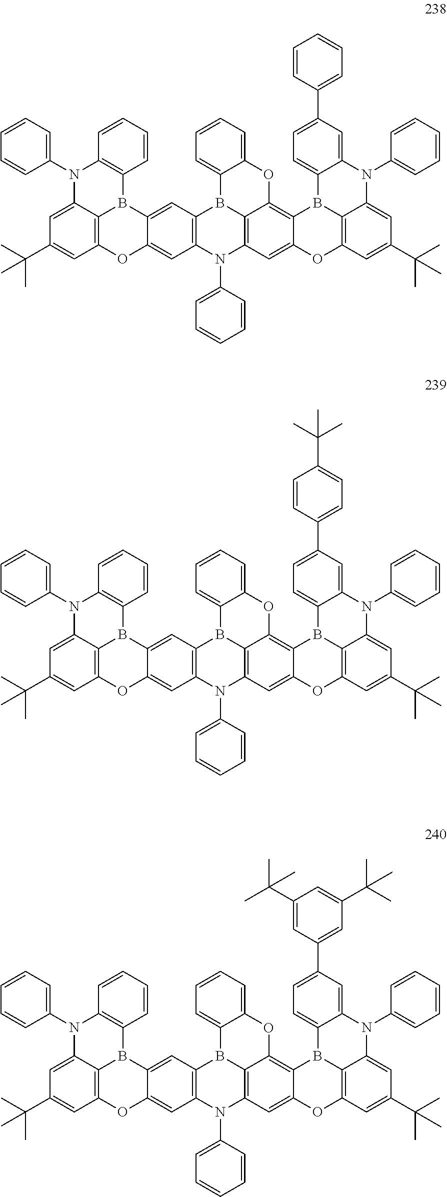 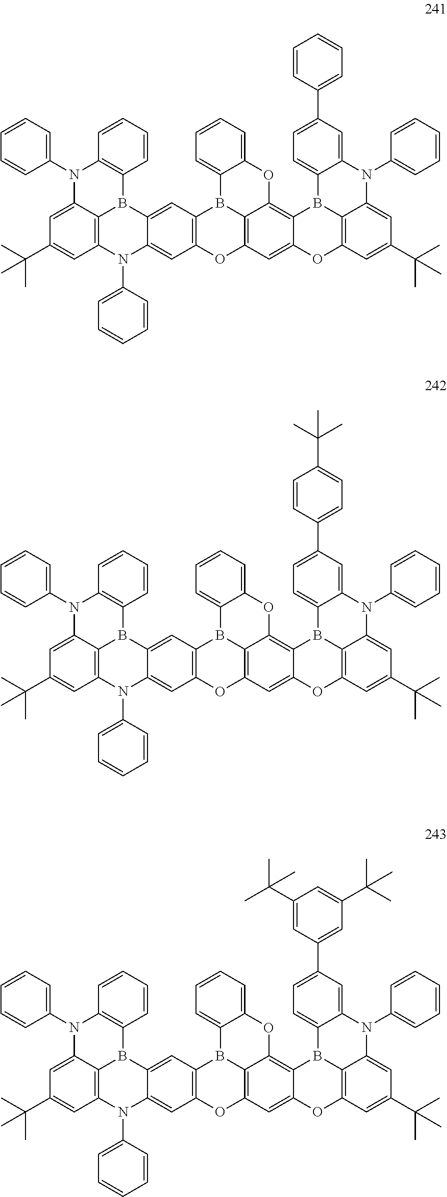 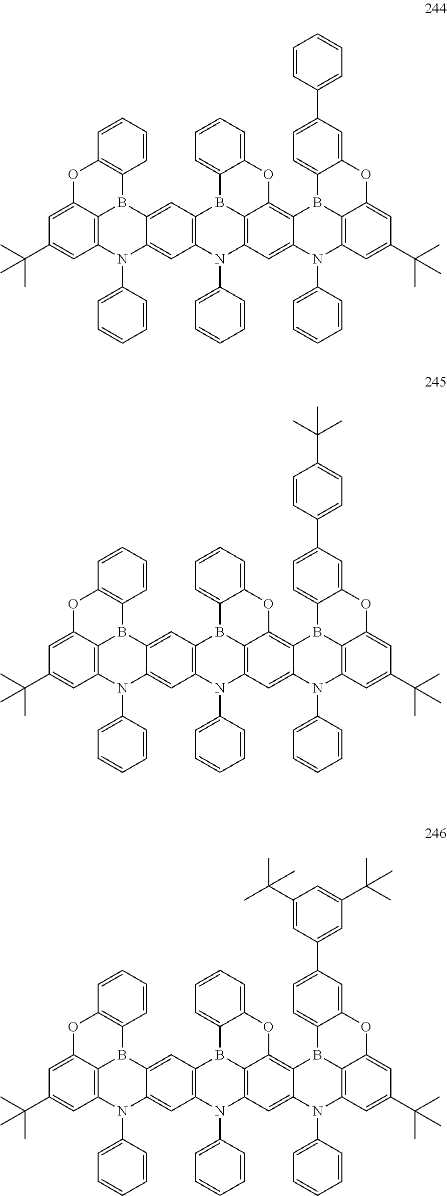 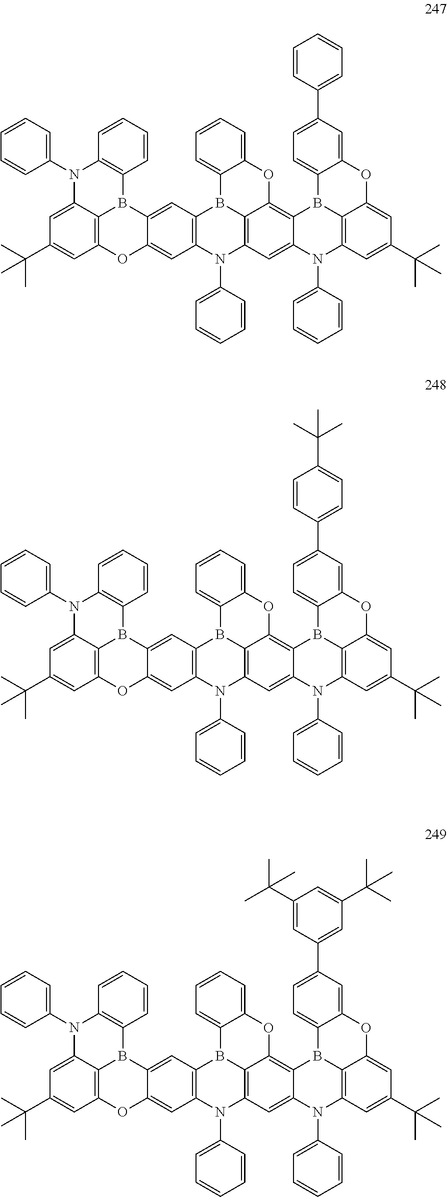 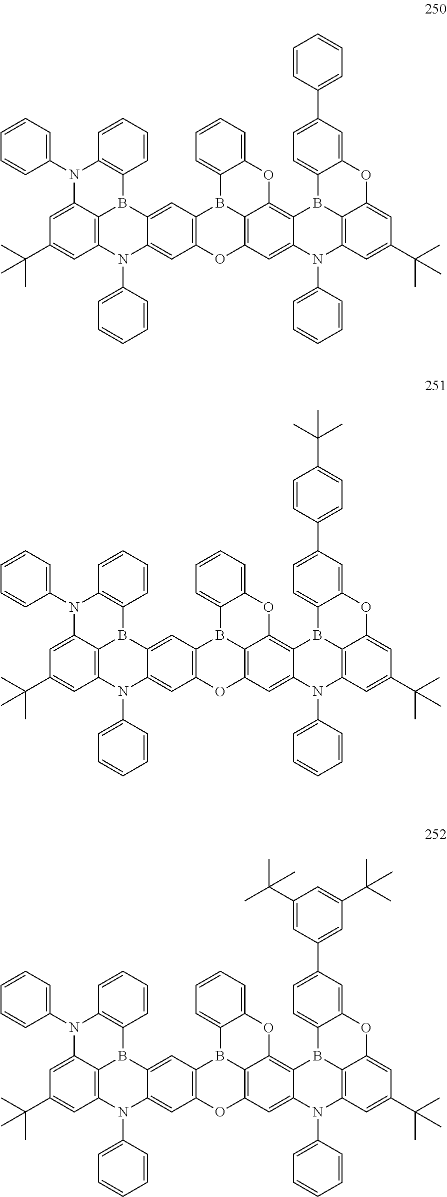 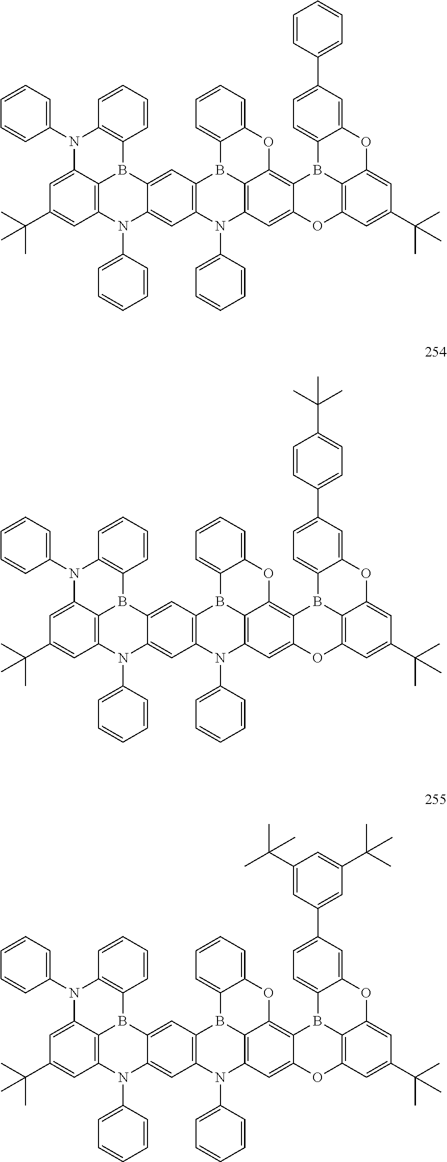 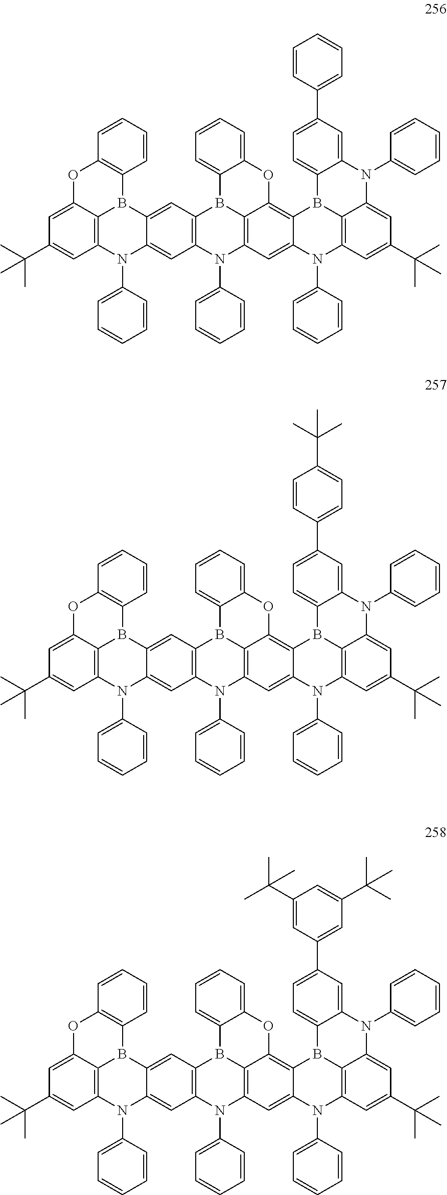 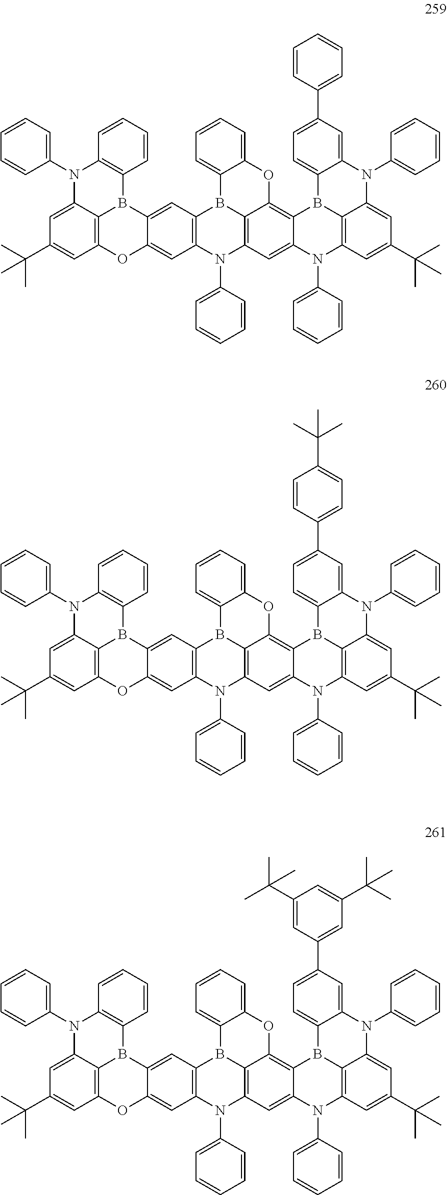 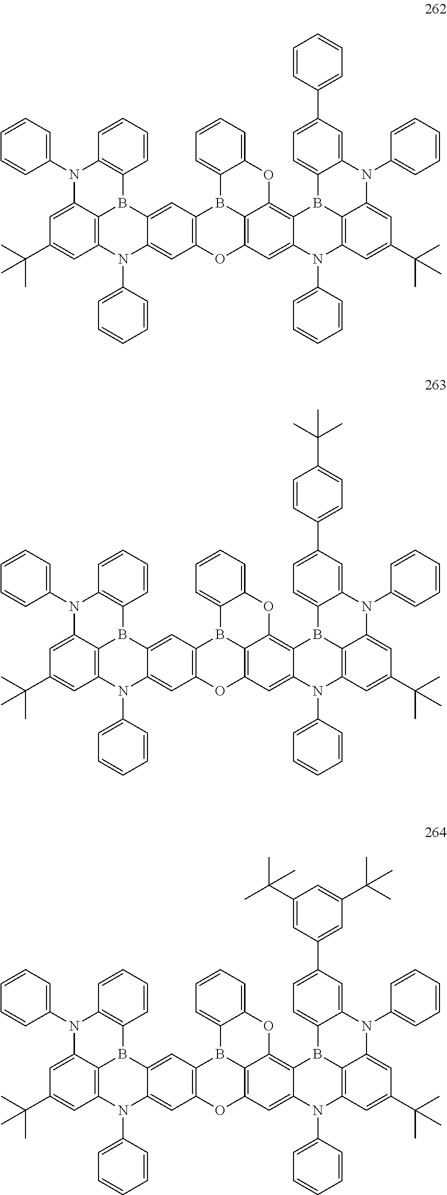 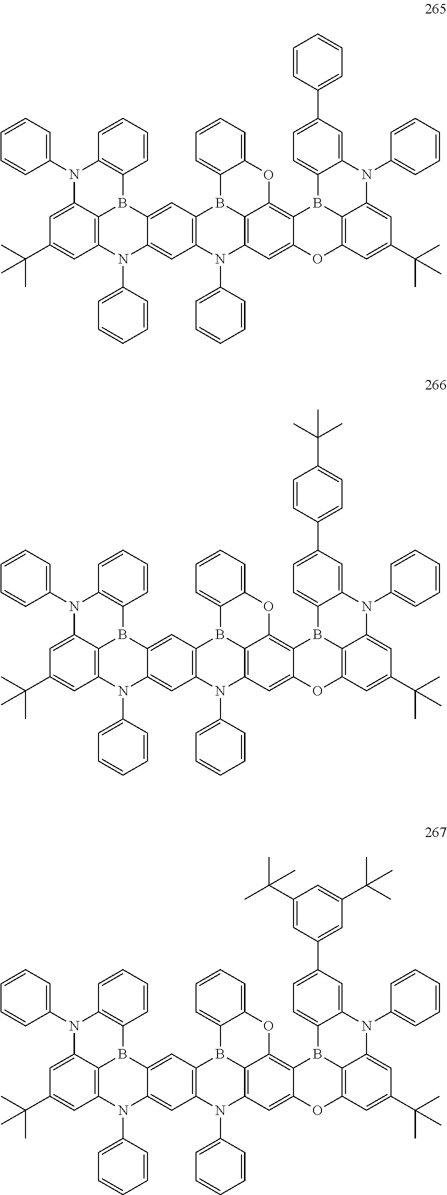 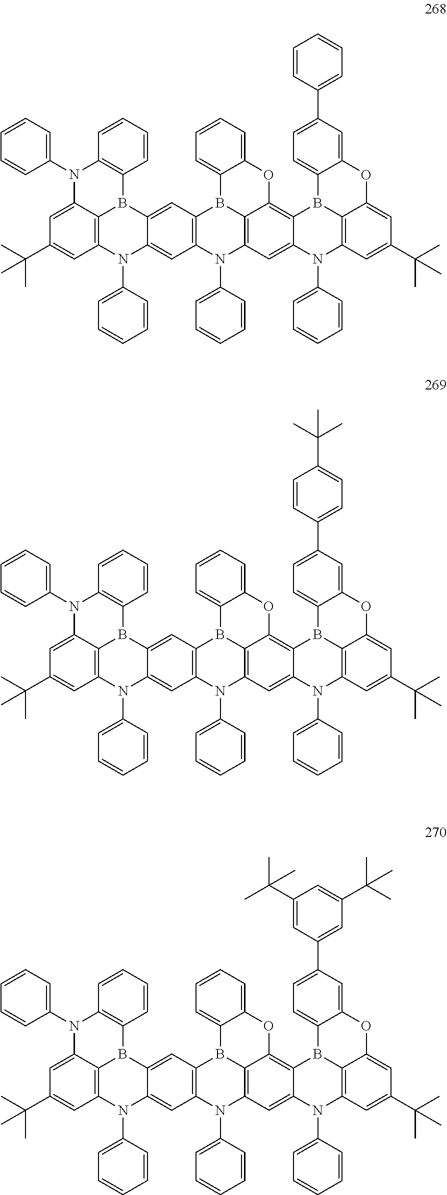 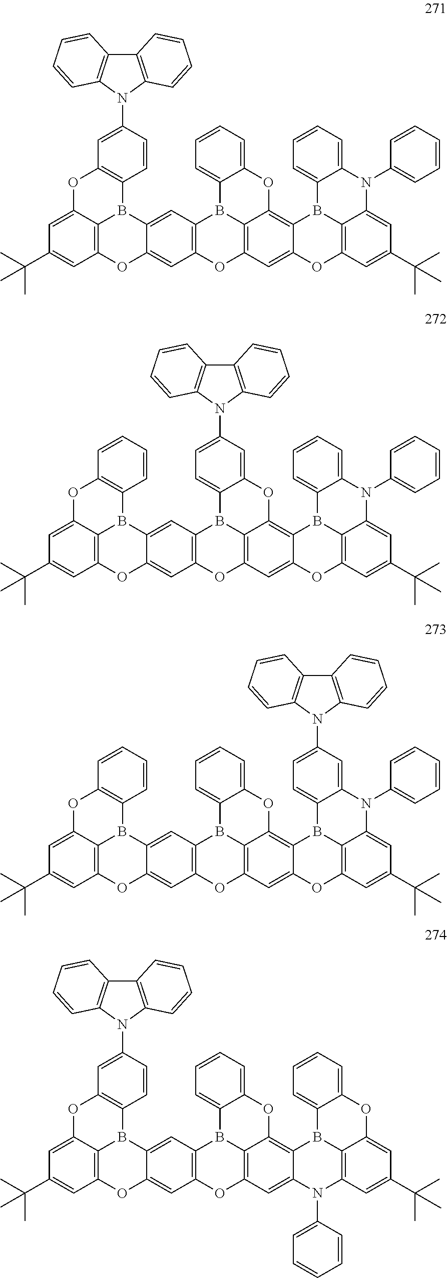 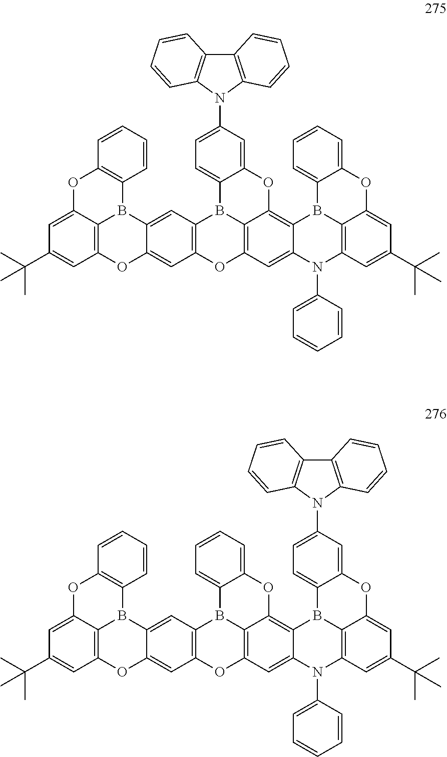 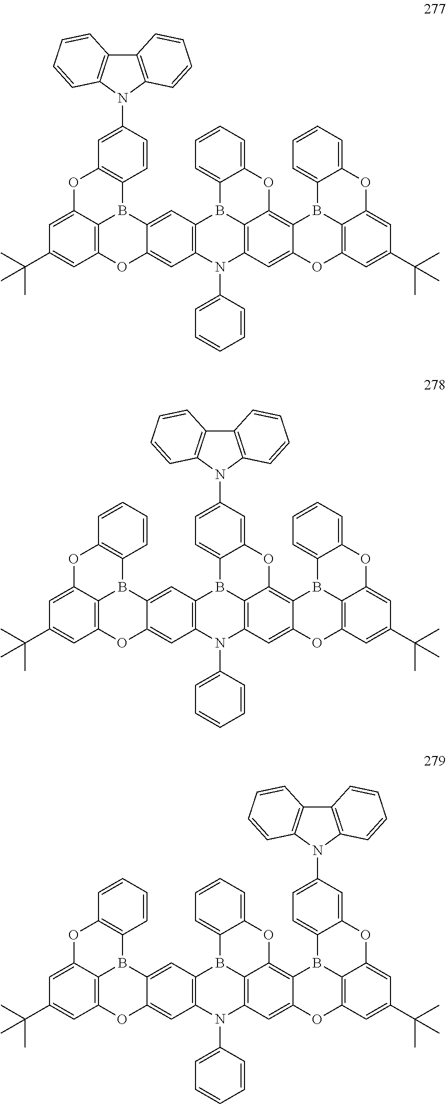 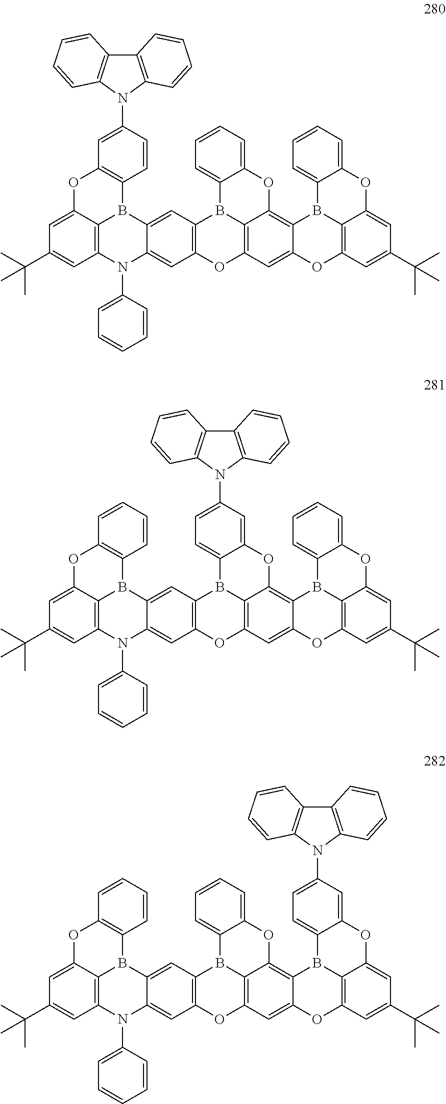 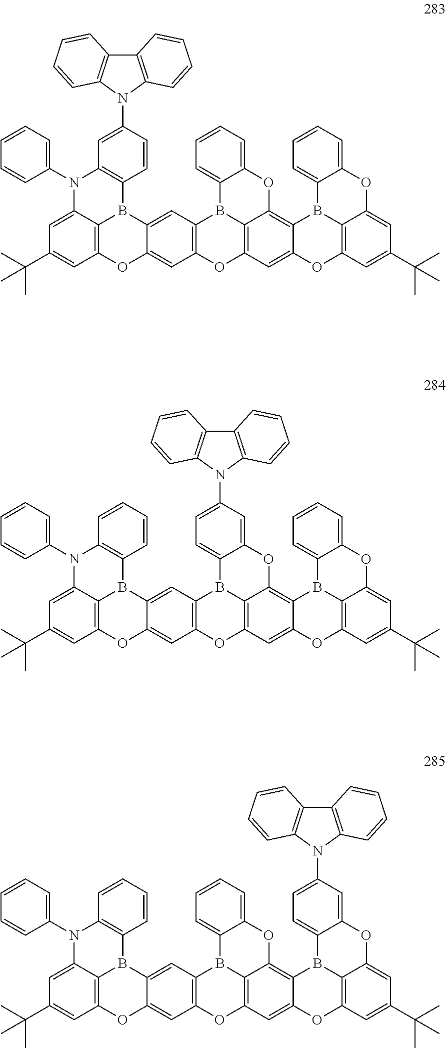 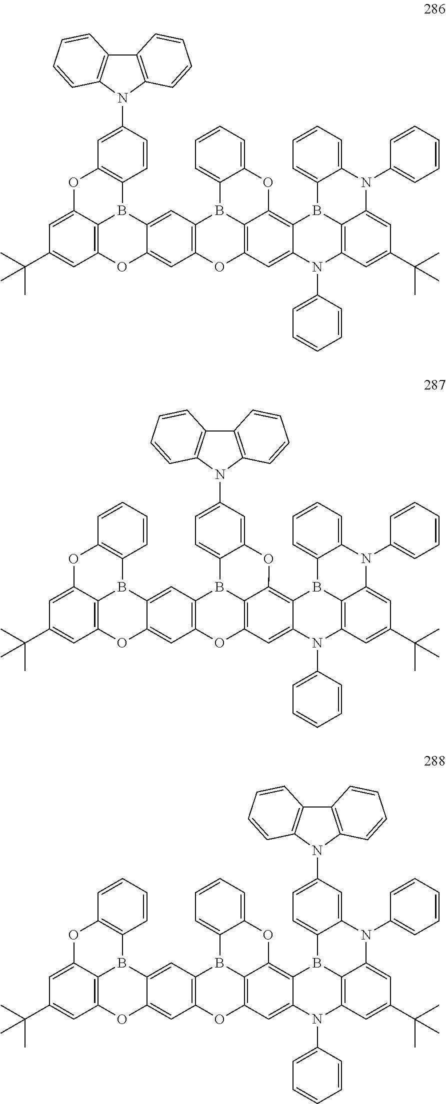 [SMILES: CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1cc2c3c(c1)Oc1cc4c(cc1B3c1ccccc1O2)B1c2ccc(-n3c5ccccc5c5ccccc53)cc2Oc2c1c(cc1c2B2c3ccccc3N(c3ccccc3)c3cc(C(C)(C)C)cc(c32)N1c1ccccc1)O4 ; CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3N(c3ccccc3)c3cc(C(C)(C)C)cc(c32)N1c1ccccc1)O4] 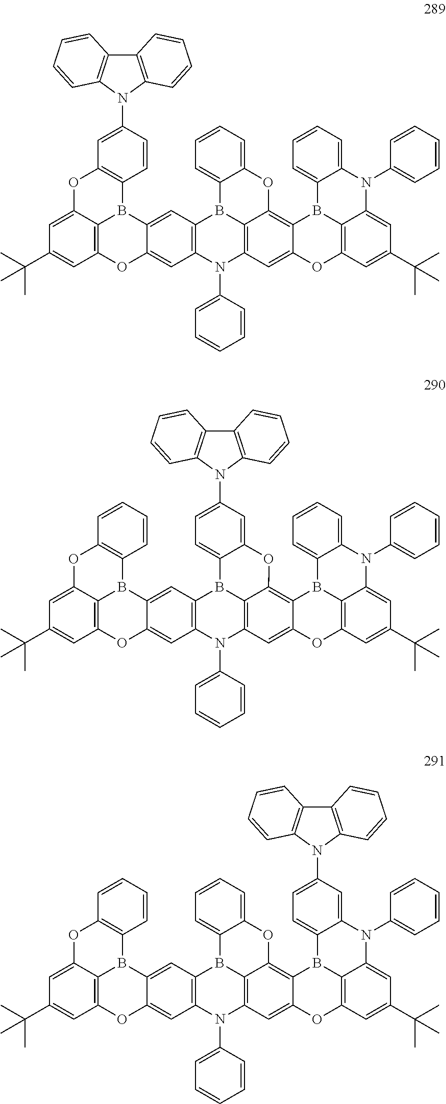 [SMILES: CC(C)(C)c1cc2c3c(c1)Oc1cc4c(cc1B3c1ccc(-n3c5ccccc5c5ccccc53)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1cc2c3c(c1)Oc1cc4c(cc1B3c1ccccc1O2)B1c2ccc(-n3c5ccccc5c5ccccc53)cc2Oc2c3c(cc(c21)N4c1ccccc1)Oc1cc(C(C)(C)C)cc2c1B3c1ccccc1N2c1ccccc1 ; CC(C)(C)c1cc2c3c(c1)Oc1cc4c(cc1B3c1ccccc1O2)B1c2ccccc2Oc2c3c(cc(c21)N4c1ccccc1)Oc1cc(C(C)(C)C)cc2c1B3c1ccc(-n3c4ccccc4c4ccccc43)cc1N2c1ccccc1] 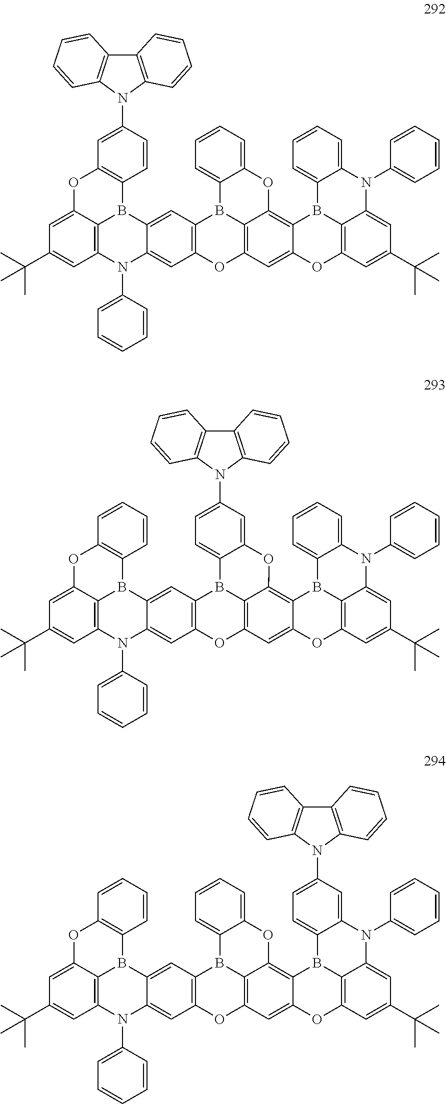 [SMILES: CC(C)(C)c1cc2c3c(c1)N(c1ccccc1)c1cc4c(cc1B3c1ccc(-n3c5ccccc5c5ccccc53)cc1O2)B1c2ccccc2Oc2c1c(cc1c2B2c3ccccc3N(c3ccccc3)c3cc(C(C)(C)C)cc(c32)O1)O4 ; CC(C)(C)c1cc2c3c(c1)N(c1ccccc1)c1cc4c(cc1B3c1ccccc1O2)B1c2ccc(-n3c5ccccc5c5ccccc53)cc2Oc2c1c(cc1c2B2c3ccccc3N(c3ccccc3)c3cc(C(C)(C)C)cc(c32)O1)O4 ; CC(C)(C)c1cc2c3c(c1)N(c1ccccc1)c1cc4c(cc1B3c1ccccc1O2)B1c2ccccc2Oc2c1c(cc1c2B2c3ccc(-n5c6ccccc6c6ccccc65)cc3N(c3ccccc3)c3cc(C(C)(C)C)cc(c32)O1)O4] 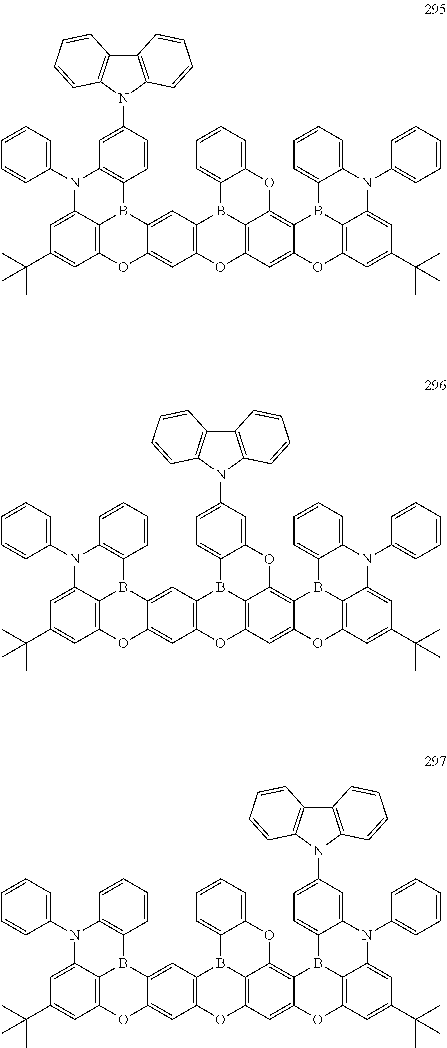 [SMILES: CC(C)(C)c1cc2c3c(c1)N(c1ccccc1)c1cc(-n4c5ccccc5c5ccccc54)ccc1B3c1cc3c(cc1O2)Oc1cc2c(c4c1B3c1ccccc1O4)B1c3ccccc3N(c3ccccc3)c3cc(C(C)(C)C)cc(c31)O2 ; CC(C)(C)c1cc2c3c(c1)N(c1ccccc1)c1ccccc1B3c1cc3c(cc1O2)Oc1cc2c(c4c1B3c1ccc(-n3c5ccccc5c5ccccc53)cc1O4)B1c3ccccc3N(c3ccccc3)c3cc(C(C)(C)C)cc(c31)O2 ; CC(C)(C)c1cc2c3c(c1)N(c1ccccc1)c1ccccc1B3c1cc3c(cc1O2)Oc1cc2c(c4c1B3c1ccccc1O4)B1c3ccc(-n4c5ccccc5c5ccccc54)cc3N(c3ccccc3)c3cc(C(C)(C)C)cc(c31)O2] 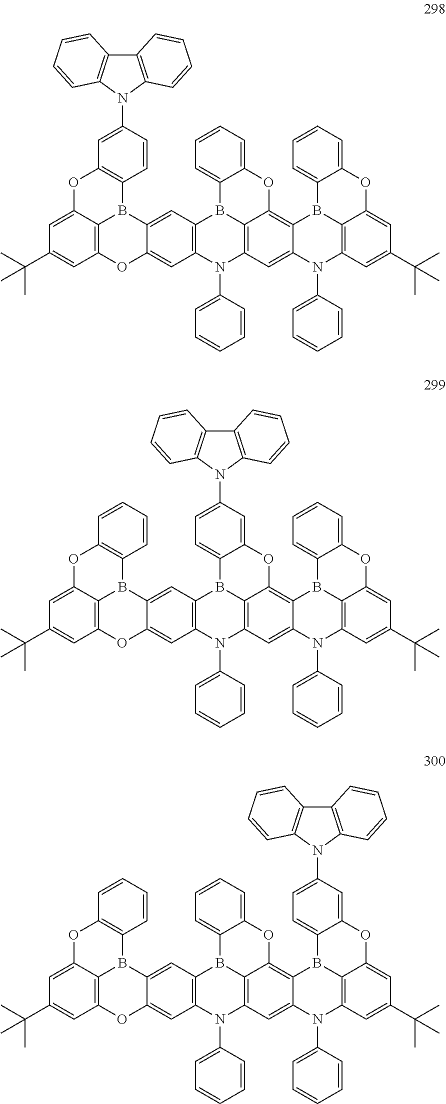 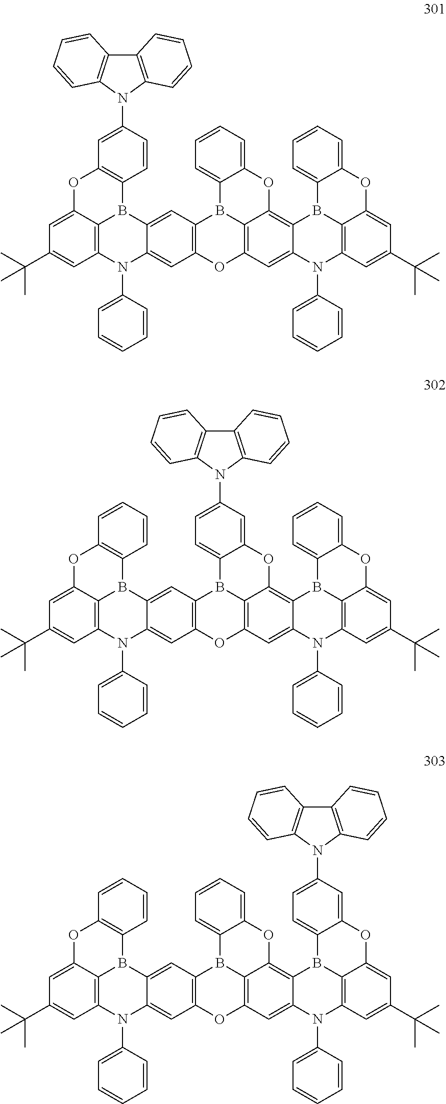 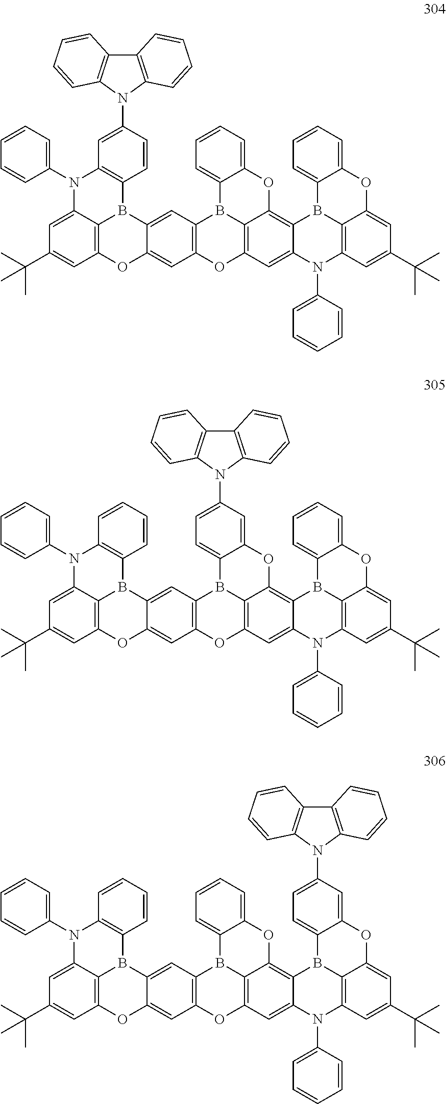 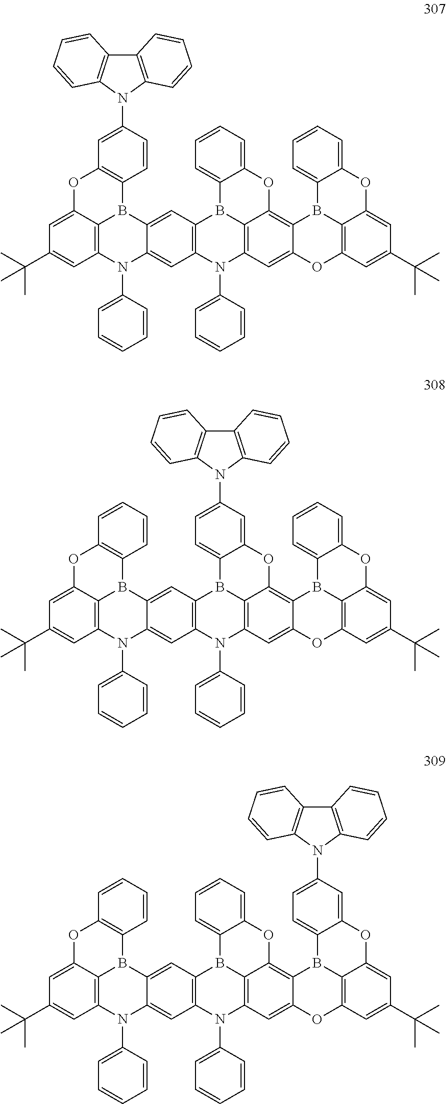 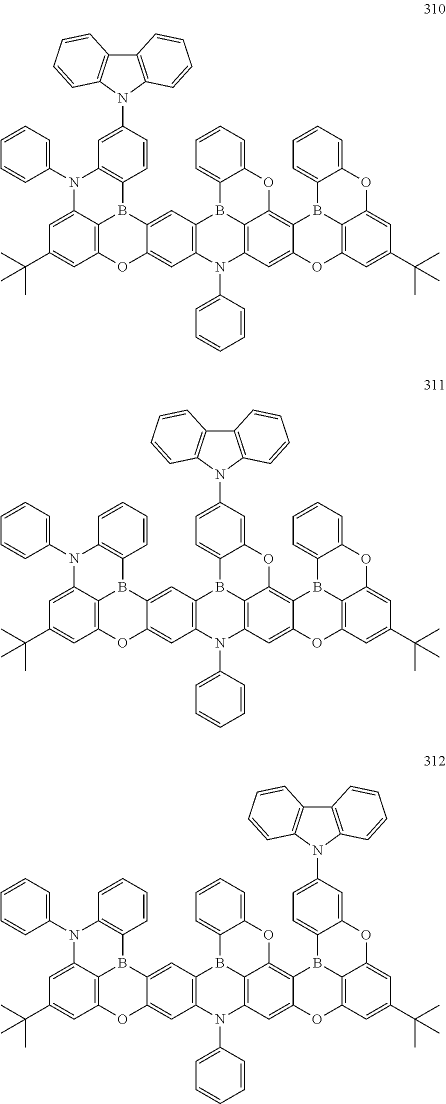 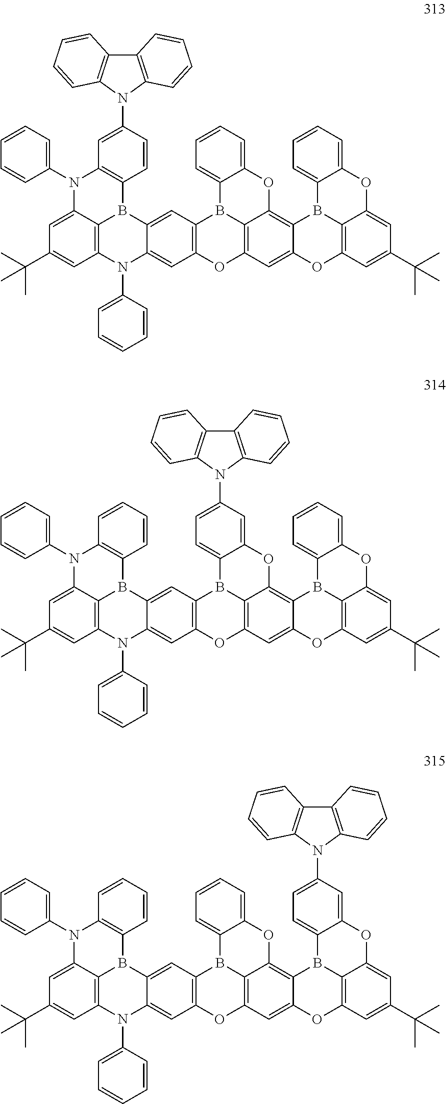 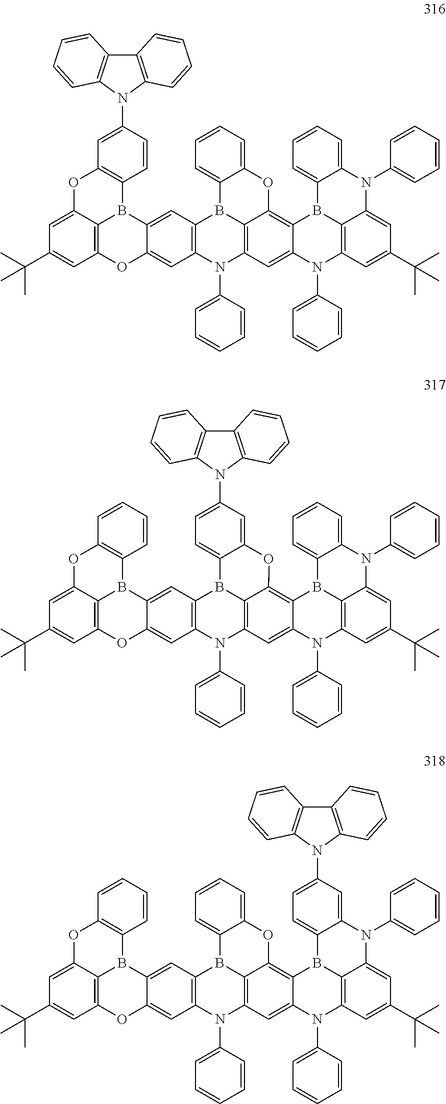 [SMILES: CC(C)(C)c1cc2c3c(c1)Oc1cc4c(cc1B3c1ccc(-n3c5ccccc5c5ccccc53)cc1O2)B1c2ccccc2Oc2c1c(cc1c2B2c3ccccc3N(c3ccccc3)c3cc(C(C)(C)C)cc(c32)N1c1ccccc1)N4c1ccccc1 ; CC(C)(C)c1cc2c3c(c1)Oc1cc4c(cc1B3c1ccccc1O2)B1c2ccc(-n3c5ccccc5c5ccccc53)cc2Oc2c1c(cc1c2B2c3ccccc3N(c3ccccc3)c3cc(C(C)(C)C)cc(c32)N1c1ccccc1)N4c1ccccc1 ; CC(C)(C)c1cc2c3c(c1)Oc1cc4c(cc1B3c1ccccc1O2)B1c2ccccc2Oc2c1c(cc1c2B2c3ccc(-n5c6ccccc6c6ccccc65)cc3N(c3ccccc3)c3cc(C(C)(C)C)cc(c32)N1c1ccccc1)N4c1ccccc1] 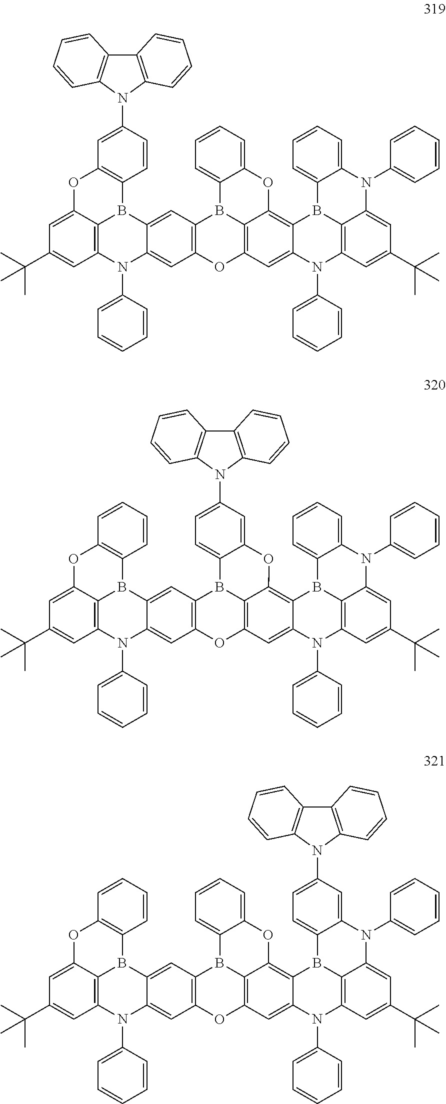 [SMILES: CC(C)(C)c1cc2c3c(c1)N(c1ccccc1)c1cc4c(cc1B3c1ccc(-n3c5ccccc5c5ccccc53)cc1O2)B1c2ccccc2Oc2c1c(cc1c2B2c3ccccc3N(c3ccccc3)c3cc(C(C)(C)C)cc(c32)N1c1ccccc1)O4 ; CC(C)(C)c1cc2c3c(c1)N(c1ccccc1)c1cc4c(cc1B3c1ccccc1O2)B1c2ccc(-n3c5ccccc5c5ccccc53)cc2Oc2c1c(cc1c2B2c3ccccc3N(c3ccccc3)c3cc(C(C)(C)C)cc(c32)N1c1ccccc1)O4 ; CC(C)(C)c1cc2c3c(c1)N(c1ccccc1)c1cc4c(cc1B3c1ccccc1O2)B1c2ccccc2Oc2c1c(cc1c2B2c3ccc(-n5c6ccccc6c6ccccc65)cc3N(c3ccccc3)c3cc(C(C)(C)C)cc(c32)N1c1ccccc1)O4] 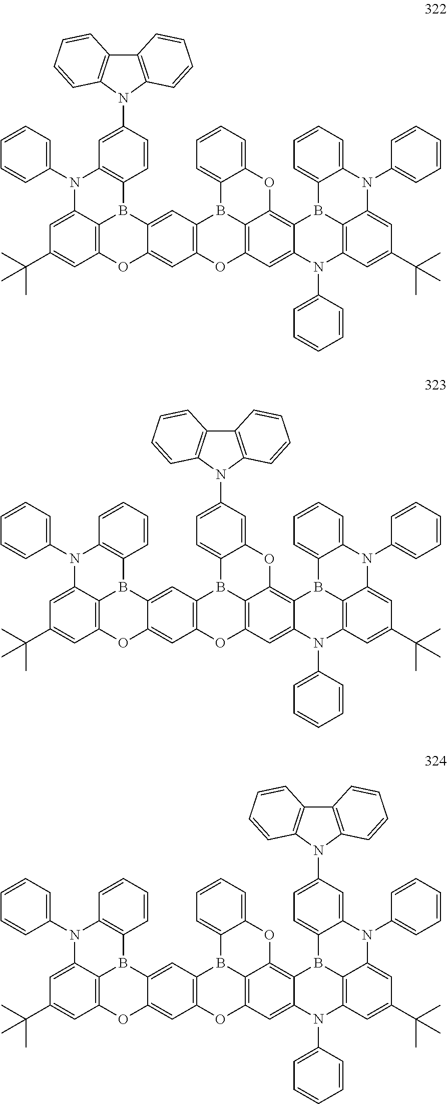 [SMILES: CC(C)(C)c1cc2c3c(c1)N(c1ccccc1)c1cc(-n4c5ccccc5c5ccccc54)ccc1B3c1cc3c(cc1O2)Oc1cc2c(c4c1B3c1ccccc1O4)B1c3ccccc3N(c3ccccc3)c3cc(C(C)(C)C)cc(c31)N2c1ccccc1 ; CC(C)(C)c1cc2c3c(c1)N(c1ccccc1)c1ccccc1B3c1cc3c(cc1O2)Oc1cc2c(c4c1B3c1ccc(-n3c5ccccc5c5ccccc53)cc1O4)B1c3ccccc3N(c3ccccc3)c3cc(C(C)(C)C)cc(c31)N2c1ccccc1 ; CC(C)(C)c1cc2c3c(c1)N(c1ccccc1)c1ccccc1B3c1cc3c(cc1O2)Oc1cc2c(c4c1B3c1ccccc1O4)B1c3ccc(-n4c5ccccc5c5ccccc54)cc3N(c3ccccc3)c3cc(C(C)(C)C)cc(c31)N2c1ccccc1] 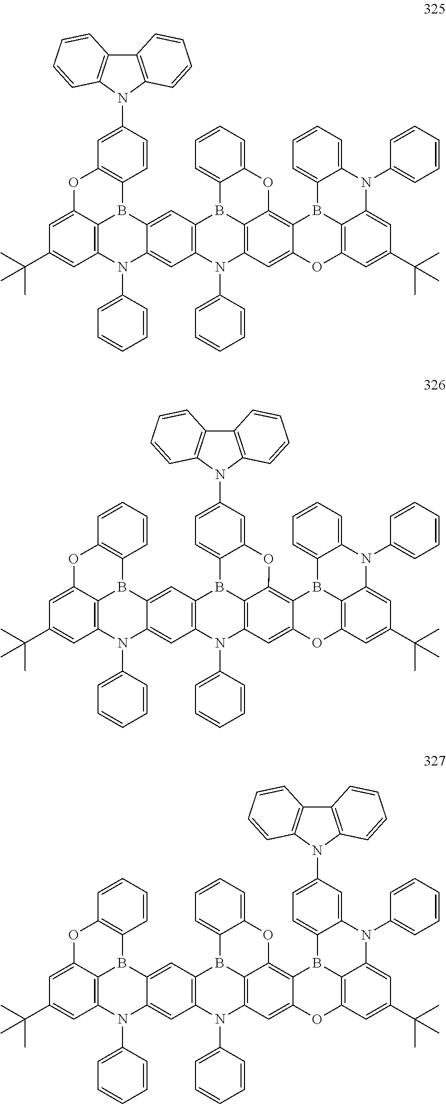 [SMILES: CC(C)(C)c1cc2c3c(c1)N(c1ccccc1)c1cc4c(cc1B3c1ccc(-n3c5ccccc5c5ccccc53)cc1O2)B1c2ccccc2Oc2c3c(cc(c21)N4c1ccccc1)Oc1cc(C(C)(C)C)cc2c1B3c1ccccc1N2c1ccccc1 ; CC(C)(C)c1cc2c3c(c1)N(c1ccccc1)c1cc4c(cc1B3c1ccccc1O2)B1c2ccc(-n3c5ccccc5c5ccccc53)cc2Oc2c3c(cc(c21)N4c1ccccc1)Oc1cc(C(C)(C)C)cc2c1B3c1ccccc1N2c1ccccc1 ; CC(C)(C)c1cc2c3c(c1)N(c1ccccc1)c1cc4c(cc1B3c1ccccc1O2)B1c2ccccc2Oc2c3c(cc(c21)N4c1ccccc1)Oc1cc(C(C)(C)C)cc2c1B3c1ccc(-n3c4ccccc4c4ccccc43)cc1N2c1ccccc1] 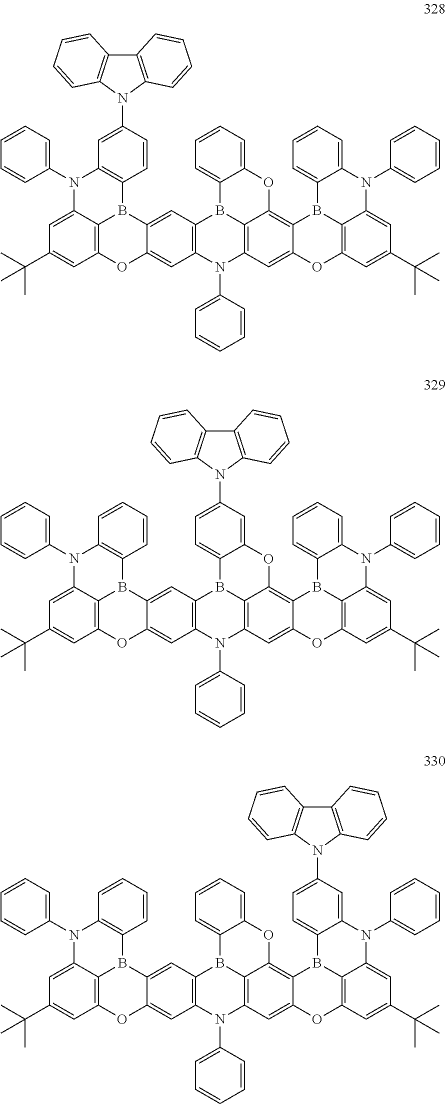 [SMILES: CC(C)(C)c1cc2c3c(c1)N(c1ccccc1)c1cc(-n4c5ccccc5c5ccccc54)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)O2 ; CC(C)(C)c1cc2c3c(c1)N(c1ccccc1)c1ccccc1B3c1cc3c(cc1O2)N(c1ccccc1)c1cc2c(c4c1B3c1ccc(-n3c5ccccc5c5ccccc53)cc1O4)B1c3ccccc3N(c3ccccc3)c3cc(C(C)(C)C)cc(c31)O2 ; CC(C)(C)c1cc2c3c(c1)N(c1ccccc1)c1ccccc1B3c1cc3c(cc1O2)N(c1ccccc1)c1cc2c(c4c1B3c1ccccc1O4)B1c3ccc(-n4c5ccccc5c5ccccc54)cc3N(c3ccccc3)c3cc(C(C)(C)C)cc(c31)O2] 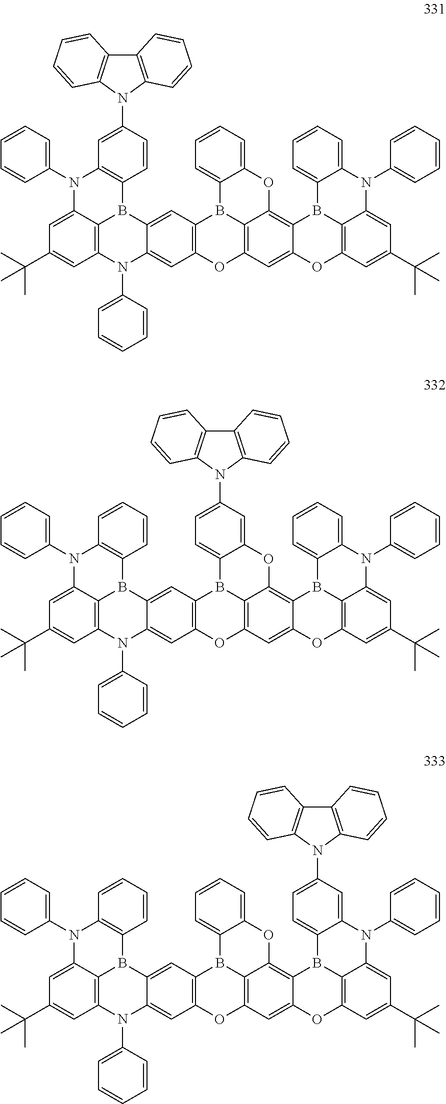 [SMILES: CC(C)(C)c1cc2c3c(c1)N(c1ccccc1)c1ccccc1B3c1c(cc3c4c1Oc1ccccc1B4c1cc4c(cc1O3)N(c1ccccc1)c1cc(C(C)(C)C)cc3c1B4c1ccc(-n4c5ccccc5c5ccccc54)cc1N3c1ccccc1)O2 ; CC(C)(C)c1cc2c3c(c1)N(c1ccccc1)c1ccccc1B3c1c(cc3c4c1Oc1cc(-n5c6ccccc6c6ccccc65)ccc1B4c1cc4c(cc1O3)N(c1ccccc1)c1cc(C(C)(C)C)cc3c1B4c1ccccc1N3c1ccccc1)O2 ; CC(C)(C)c1cc2c3c(c1)N(c1ccccc1)c1cc(-n4c5ccccc5c5ccccc54)ccc1B3c1c(cc3c4c1Oc1ccccc1B4c1cc4c(cc1O3)N(c1ccccc1)c1cc(C(C)(C)C)cc3c1B4c1ccccc1N3c1ccccc1)O2] 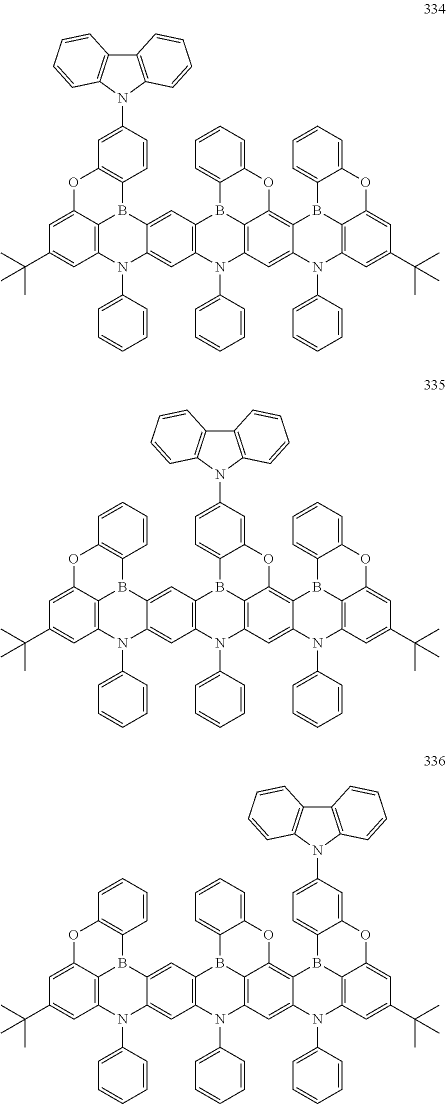 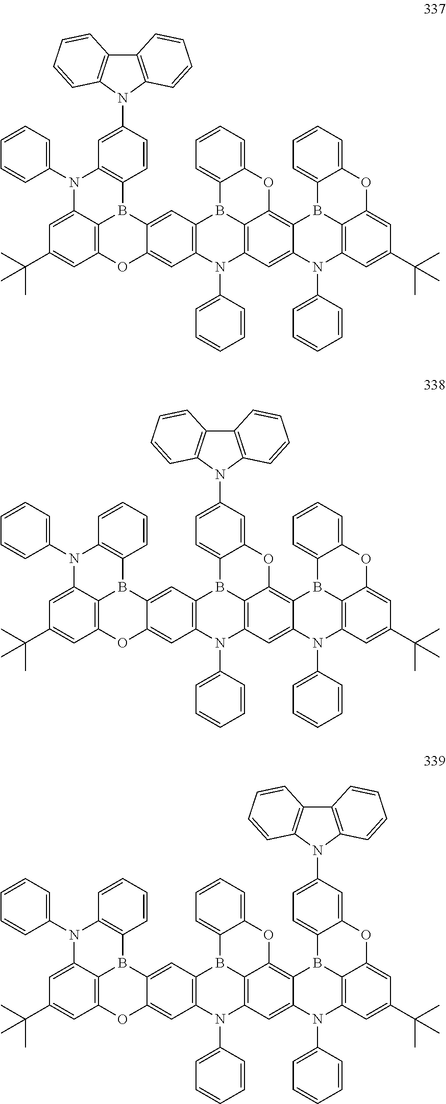 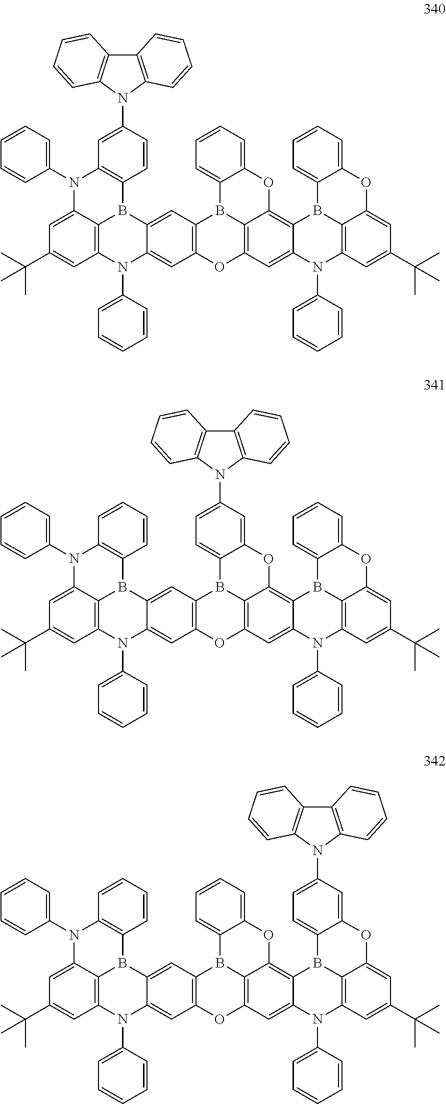 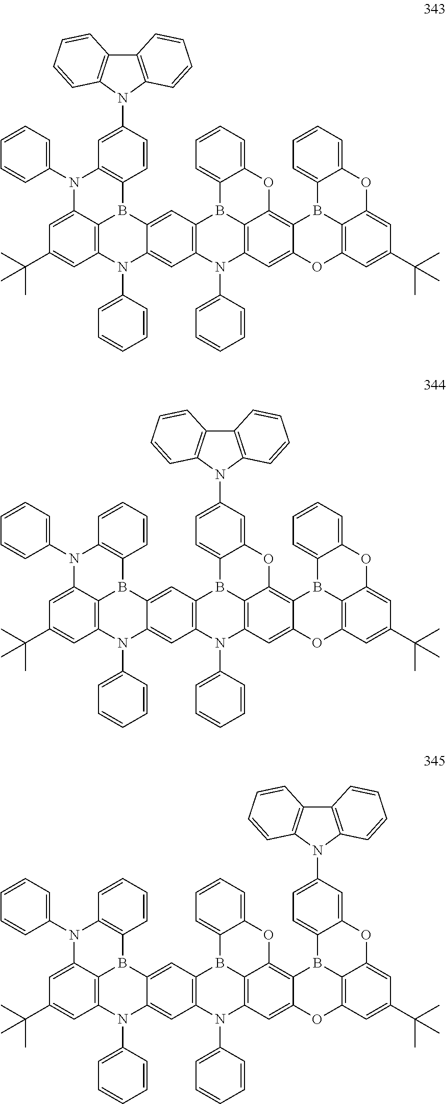 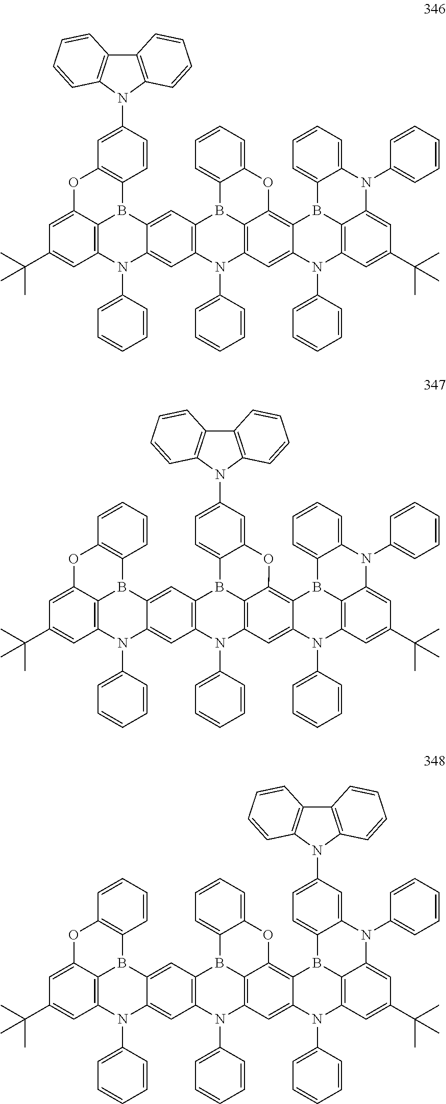 [SMILES: CC(C)(C)c1cc2c3c(c1)N(c1ccccc1)c1cc4c(cc1B3c1ccc(-n3c5ccccc5c5ccccc53)cc1O2)B1c2ccccc2Oc2c1c(cc1c2B2c3ccccc3N(c3ccccc3)c3cc(C(C)(C)C)cc(c32)N1c1ccccc1)N4c1ccccc1 ; CC(C)(C)c1cc2c3c(c1)N(c1ccccc1)c1cc4c(cc1B3c1ccccc1O2)B1c2ccc(-n3c5ccccc5c5ccccc53)cc2Oc2c1c(cc1c2B2c3ccccc3N(c3ccccc3)c3cc(C(C)(C)C)cc(c32)N1c1ccccc1)N4c1ccccc1 ; CC(C)(C)c1cc2c3c(c1)N(c1ccccc1)c1cc4c(cc1B3c1ccccc1O2)B1c2ccccc2Oc2c1c(cc1c2B2c3ccc(-n5c6ccccc6c6ccccc65)cc3N(c3ccccc3)c3cc(C(C)(C)C)cc(c32)N1c1ccccc1)N4c1ccccc1] 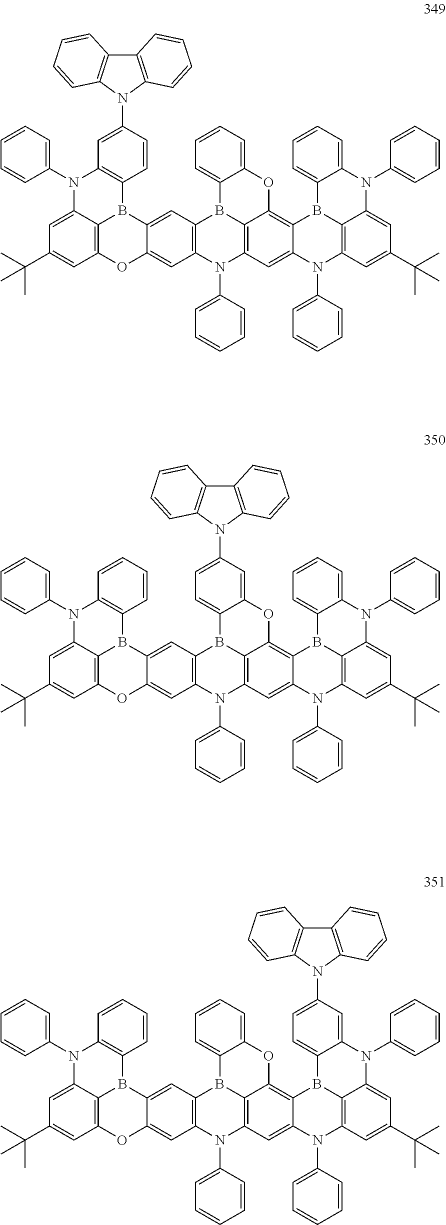 [SMILES: CC(C)(C)c1cc2c3c(c1)N(c1ccccc1)c1cc(-n4c5ccccc5c5ccccc54)ccc1B3c1cc3c(cc1O2)N(c1ccccc1)c1cc2c(c4c1B3c1ccccc1O4)B1c3ccccc3N(c3ccccc3)c3cc(C(C)(C)C)cc(c31)N2c1ccccc1 ; CC(C)(C)c1cc2c3c(c1)N(c1ccccc1)c1ccccc1B3c1cc3c(cc1O2)N(c1ccccc1)c1cc2c(c4c1B3c1ccc(-n3c5ccccc5c5ccccc53)cc1O4)B1c3ccccc3N(c3ccccc3)c3cc(C(C)(C)C)cc(c31)N2c1ccccc1 ; CC(C)(C)c1cc2c3c(c1)N(c1ccccc1)c1ccccc1B3c1cc3c(cc1O2)N(c1ccccc1)c1cc2c(c4c1B3c1ccccc1O4)B1c3ccc(-n4c5ccccc5c5ccccc54)cc3N(c3ccccc3)c3cc(C(C)(C)C)cc(c31)N2c1ccccc1] 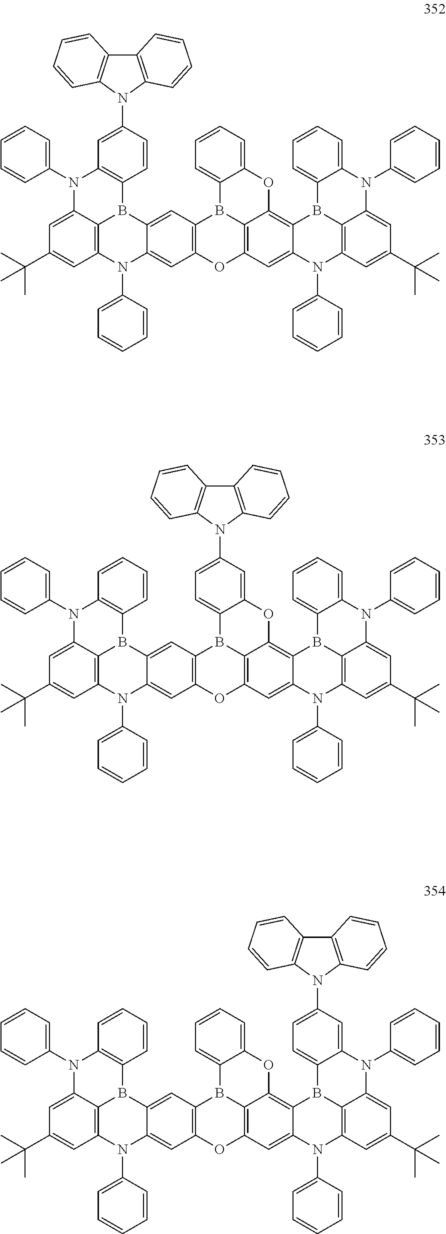 [SMILES: CC(C)(C)c1cc2c3c(c1)N(c1ccccc1)c1cc4c(cc1B3c1ccc(-n3c5ccccc5c5ccccc53)cc1N2c1ccccc1)B1c2ccccc2Oc2c1c(cc1c2B2c3ccccc3N(c3ccccc3)c3cc(C(C)(C)C)cc(c32)N1c1ccccc1)O4 ; CC(C)(C)c1cc2c3c(c1)N(c1ccccc1)c1cc4c(cc1B3c1ccccc1N2c1ccccc1)B1c2ccc(-n3c5ccccc5c5ccccc53)cc2Oc2c1c(cc1c2B2c3ccccc3N(c3ccccc3)c3cc(C(C)(C)C)cc(c32)N1c1ccccc1)O4 ; CC(C)(C)c1cc2c3c(c1)N(c1ccccc1)c1cc4c(cc1B3c1ccccc1N2c1ccccc1)B1c2ccccc2Oc2c1c(cc1c2B2c3ccc(-n5c6ccccc6c6ccccc65)cc3N(c3ccccc3)c3cc(C(C)(C)C)cc(c32)N1c1ccccc1)O4] 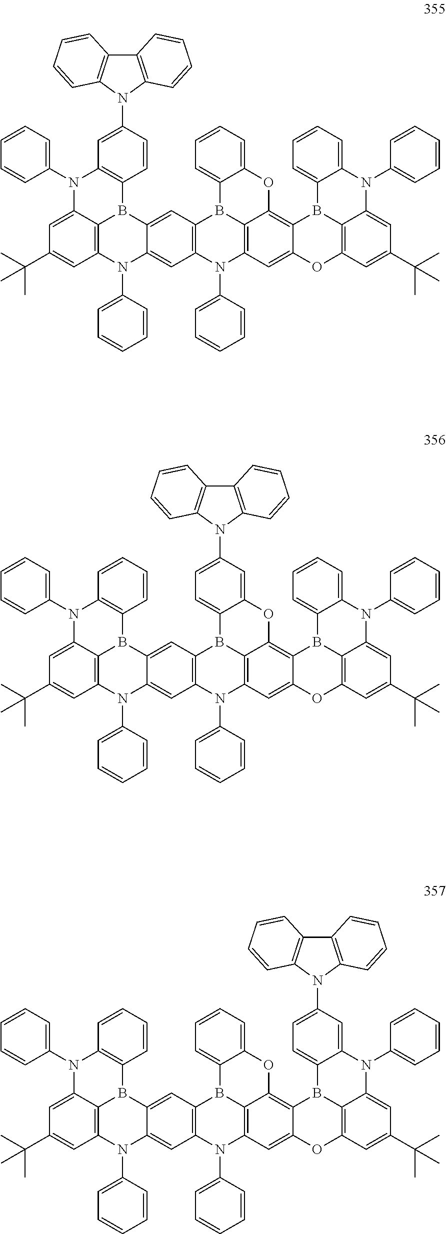 [SMILES: CC(C)(C)c1cc2c3c(c1)N(c1ccccc1)c1ccccc1B3c1c(cc3c4c1Oc1ccccc1B4c1cc4c(cc1N3c1ccccc1)N(c1ccccc1)c1cc(C(C)(C)C)cc3c1B4c1ccc(-n4c5ccccc5c5ccccc54)cc1N3c1ccccc1)O2 ; CC(C)(C)c1cc2c3c(c1)N(c1ccccc1)c1ccccc1B3c1c(cc3c4c1Oc1cc(-n5c6ccccc6c6ccccc65)ccc1B4c1cc4c(cc1N3c1ccccc1)N(c1ccccc1)c1cc(C(C)(C)C)cc3c1B4c1ccccc1N3c1ccccc1)O2 ; CC(C)(C)c1cc2c3c(c1)N(c1ccccc1)c1cc(-n4c5ccccc5c5ccccc54)ccc1B3c1c(cc3c4c1Oc1ccccc1B4c1cc4c(cc1N3c1ccccc1)N(c1ccccc1)c1cc(C(C)(C)C)cc3c1B4c1ccccc1N3c1ccccc1)O2] 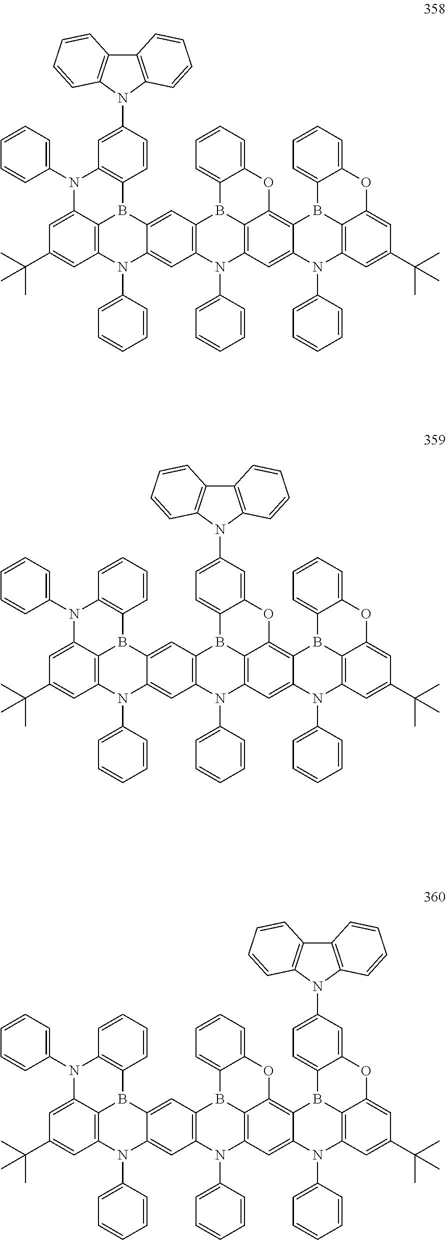 [SMILES: CC(C)(C)c1cc2c3c(c1)N(c1ccccc1)c1cc4c5c(c1B3c1ccccc1O2)Oc1ccccc1B5c1cc2c(cc1N4c1ccccc1)N(c1ccccc1)c1cc(C(C)(C)C)cc3c1B2c1ccc(-n2c4ccccc4c4ccccc42)cc1N3c1ccccc1 ; CC(C)(C)c1cc2c3c(c1)N(c1ccccc1)c1cc4c5c(c1B3c1ccccc1O2)Oc1cc(-n2c3ccccc3c3ccccc32)ccc1B5c1cc2c(cc1N4c1ccccc1)N(c1ccccc1)c1cc(C(C)(C)C)cc3c1B2c1ccccc1N3c1ccccc1 ; CC(C)(C)c1cc2c3c(c1)N(c1ccccc1)c1cc4c5c(c1B3c1ccc(-n3c6ccccc6c6ccccc63)cc1O2)Oc1ccccc1B5c1cc2c(cc1N4c1ccccc1)N(c1ccccc1)c1cc(C(C)(C)C)cc3c1B2c1ccccc1N3c1ccccc1] 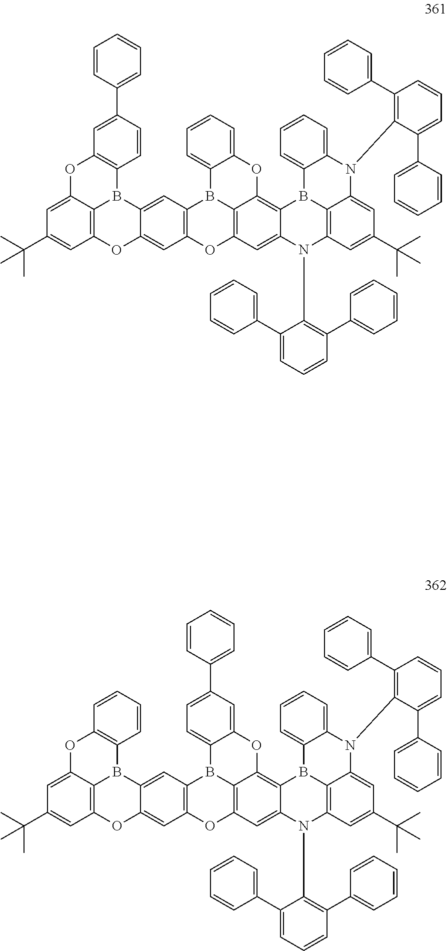 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)O4 ; CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)O4] 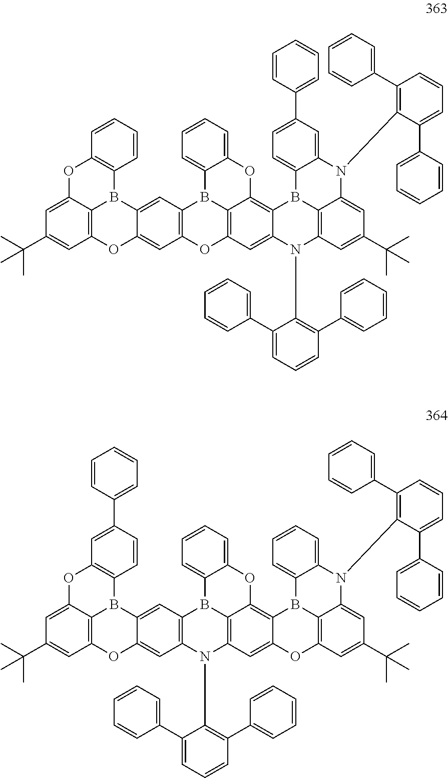 [SMILES: CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)N1c1c(-c2ccccc2)cccc1-c1ccccc1)O4 ; CC(C)(C)c1cc2c3c(c1)Oc1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(C(C)(C)C)cc2c1B3c1ccccc1N2c1c(-c2ccccc2)cccc1-c1ccccc1] 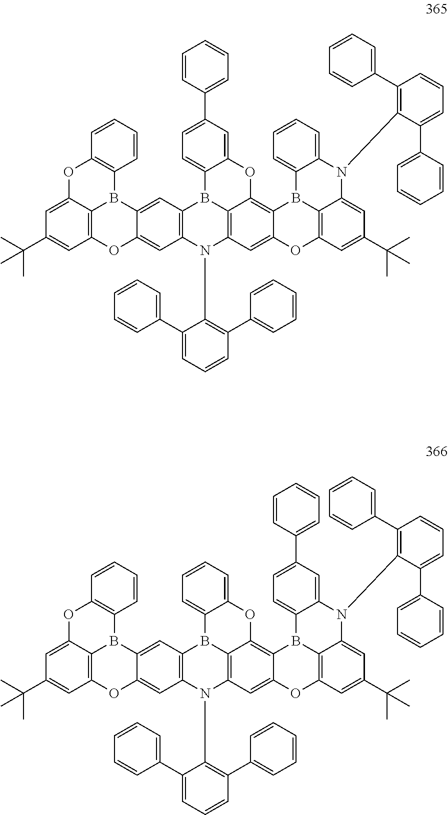 [SMILES: CC(C)(C)c1cc2c3c(c1)Oc1cc4c(cc1B3c1ccccc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccccc1N2c1c(-c2ccccc2)cccc1-c1ccccc1 ; CC(C)(C)c1cc2c3c(c1)Oc1cc4c(cc1B3c1ccccc1O2)B1c2ccccc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1] 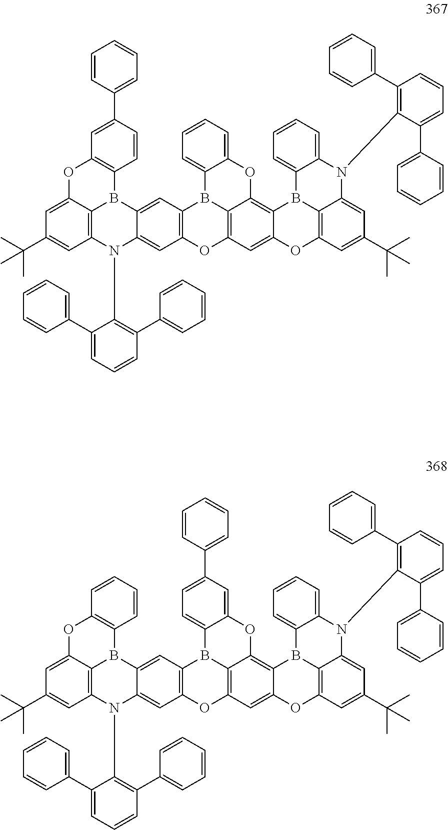 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)O1)O4 ; CC(C)(C)c1cc2c3c(c1)N(c1c(-c4ccccc4)cccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)O1)O4] 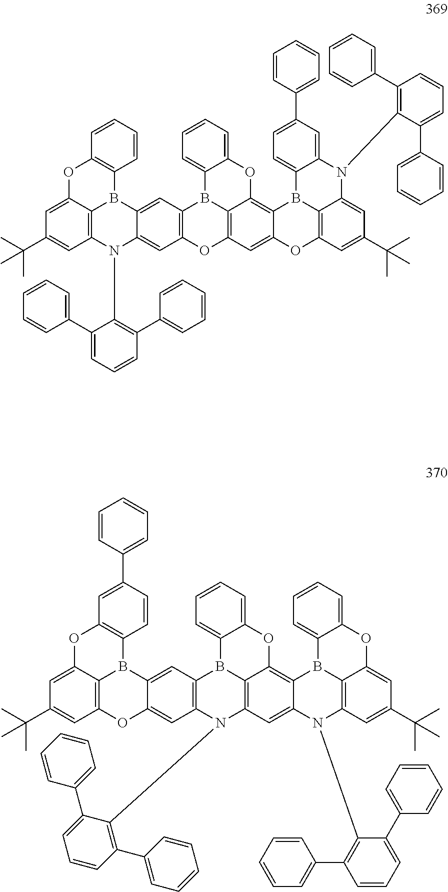 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)O1)O4 ; CC(C)(C)c1cc2c3c(c1)Oc1cc4c(cc1B3c1ccc(-c3ccccc3)cc1O2)B1c2ccccc2Oc2c1c(cc1c2B2c3ccccc3Oc3cc(C(C)(C)C)cc(c32)N1c1c(-c2ccccc2)cccc1-c1ccccc1)N4c1c(-c2ccccc2)cccc1-c1ccccc1] 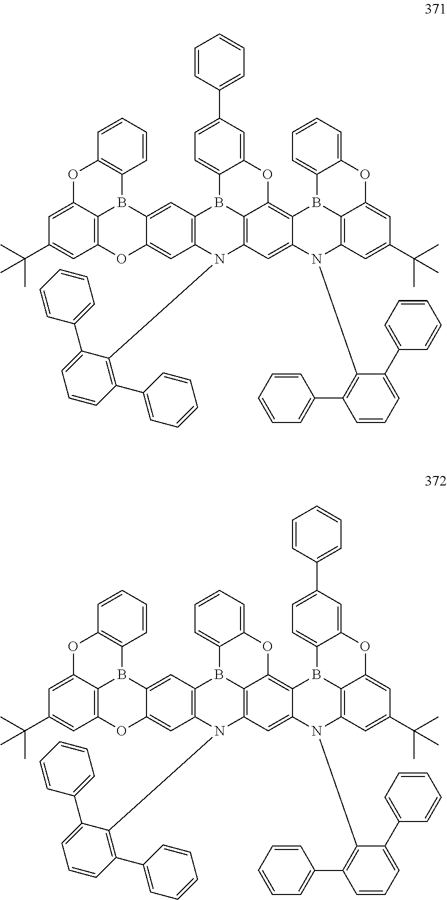 [SMILES: CC(C)(C)c1cc2c3c(c1)Oc1cc4c(cc1B3c1ccccc1O2)B1c2ccc(-c3ccccc3)cc2Oc2c1c(cc1c2B2c3ccccc3Oc3cc(C(C)(C)C)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccccc1O2)B1c2ccccc2Oc2c1c(cc1c2B2c3ccc(-c5ccccc5)cc3Oc3cc(C(C)(C)C)cc(c32)N1c1c(-c2ccccc2)cccc1-c1ccccc1)N4c1c(-c2ccccc2)cccc1-c1ccccc1] 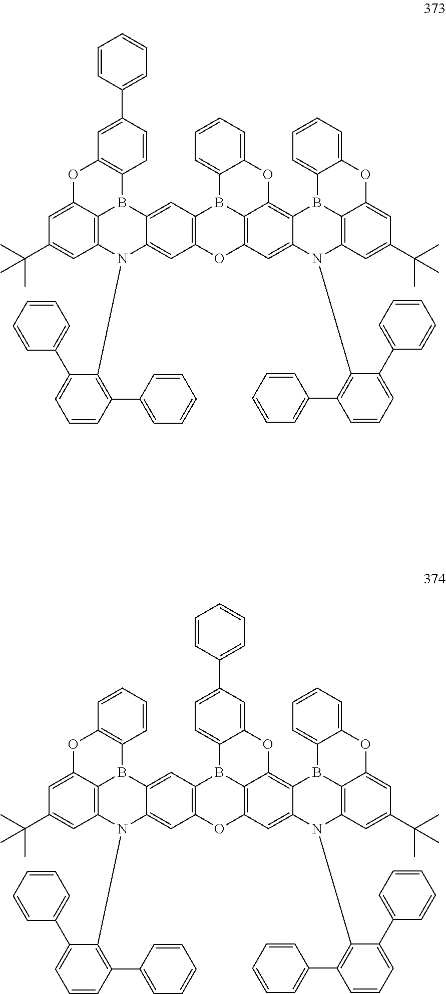 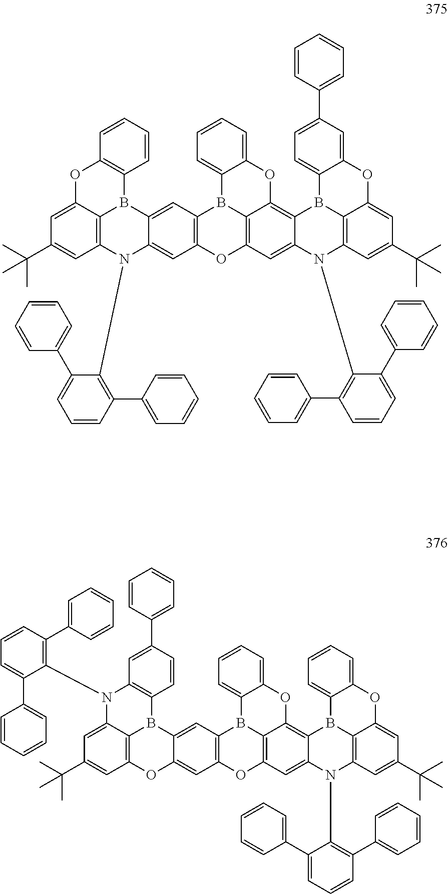 [SMILES: CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-c5ccccc5)cc3Oc3cc(C(C)(C)C)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccccc3Oc3cc(C(C)(C)C)cc(c31)N2c1c(-c2ccccc2)cccc1-c1ccccc1] 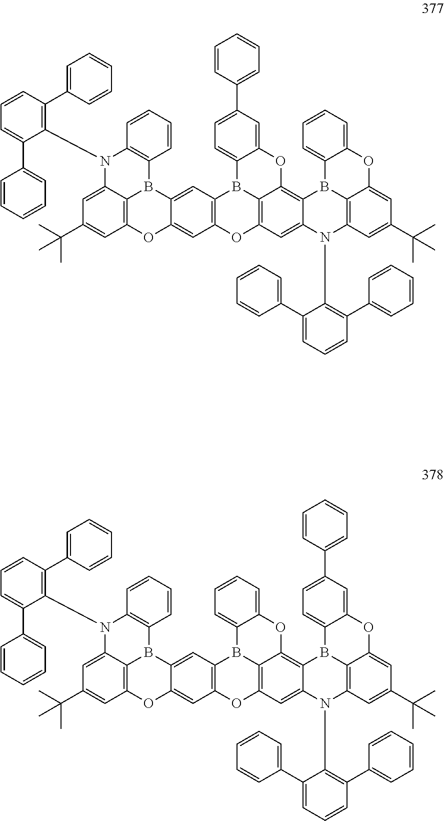 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-c3ccccc3)cc1O4)B1c3ccccc3Oc3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-c4ccccc4)cc3Oc3cc(C(C)(C)C)cc(c31)N2c1c(-c2ccccc2)cccc1-c1ccccc1] 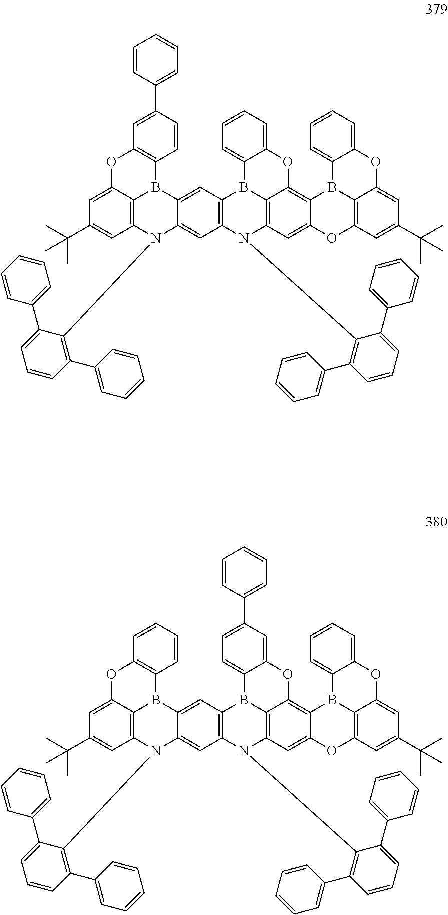 [SMILES: CC(C)(C)c1cc2c3c(c1)Oc1cc4c5c(c1B3c1ccccc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-c2ccccc2)cc1O3 ; CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccccc1O3] 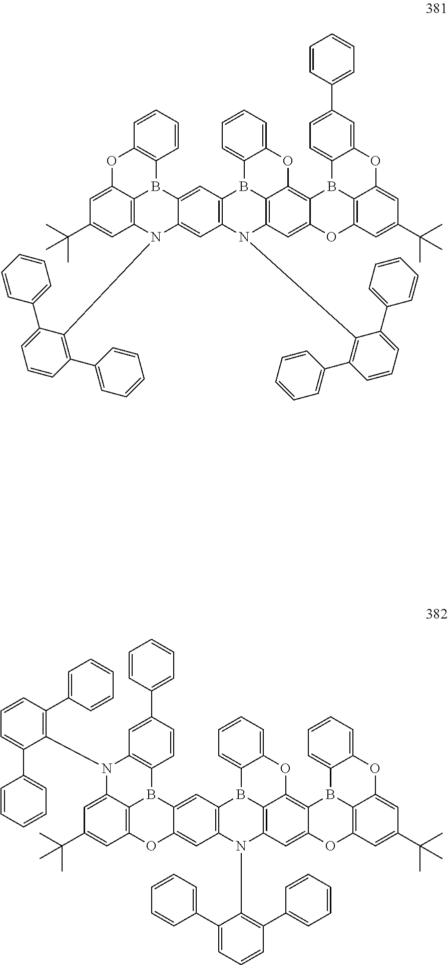 [SMILES: CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccccc1O3 ; CC(C)(C)c1cc2c3c(c1)Oc1cc4c5c(c1B3c1ccccc1O2)Oc1ccccc1B5c1cc2c(cc1N4c1c(-c3ccccc3)cccc1-c1ccccc1)Oc1cc(C(C)(C)C)cc3c1B2c1ccc(-c2ccccc2)cc1N3c1c(-c2ccccc2)cccc1-c1ccccc1] 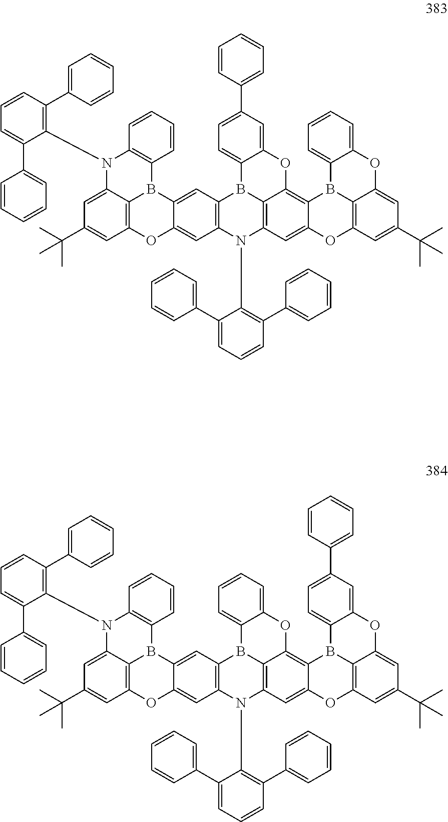 [SMILES: CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)Oc1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)Oc1cc(C(C)(C)C)cc3c1B2c1ccccc1N3c1c(-c2ccccc2)cccc1-c1ccccc1] 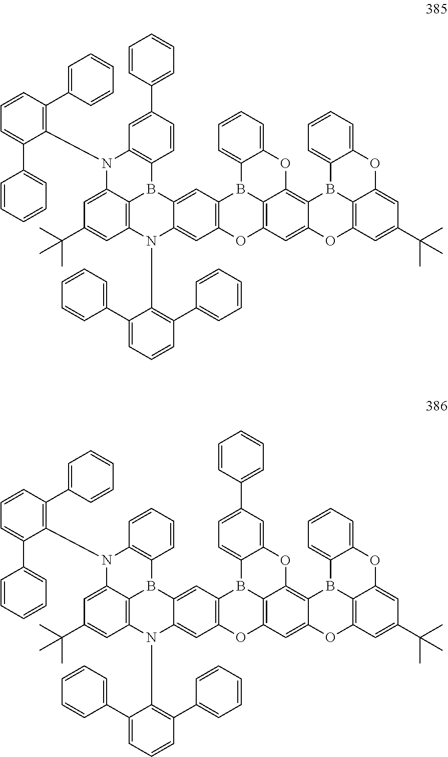 [SMILES: CC(C)(C)c1cc2c3c(c1)Oc1cc4c5c(c1B3c1ccccc1O2)Oc1ccccc1B5c1cc2c(cc1O4)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(C(C)(C)C)cc3c1B2c1ccccc1N3c1c(-c2ccccc2)cccc1-c1ccccc1] 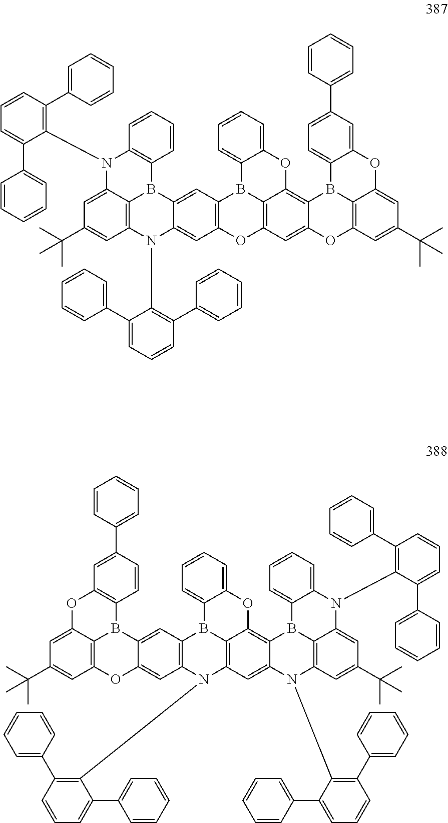 [SMILES: CC(C)(C)c1cc2c3c(c1)Oc1cc4c5c(c1B3c1ccc(-c3ccccc3)cc1O2)Oc1ccccc1B5c1cc2c(cc1O4)N(c1c(-c3ccccc3)cccc1-c1ccccc1)c1cc(C(C)(C)C)cc3c1B2c1ccccc1N3c1c(-c2ccccc2)cccc1-c1ccccc1 ; CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)N4c1c(-c2ccccc2)cccc1-c1ccccc1] 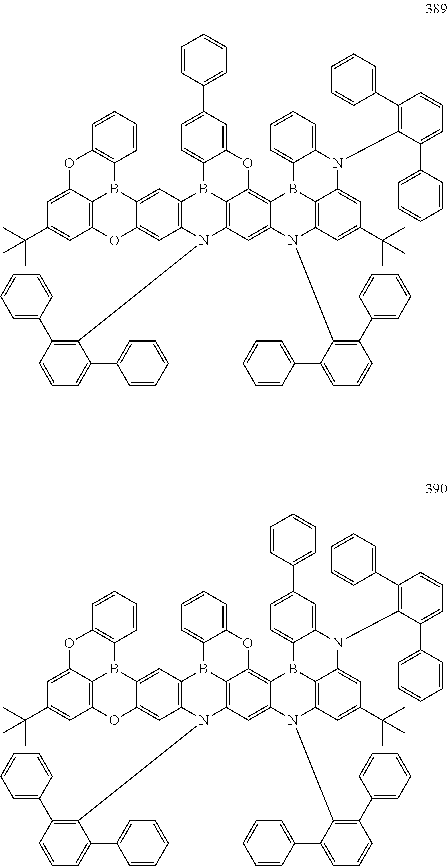 [SMILES: CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)N4c1c(-c2ccccc2)cccc1-c1ccccc1 ; CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)N1c1c(-c2ccccc2)cccc1-c1ccccc1)N4c1c(-c2ccccc2)cccc1-c1ccccc1] 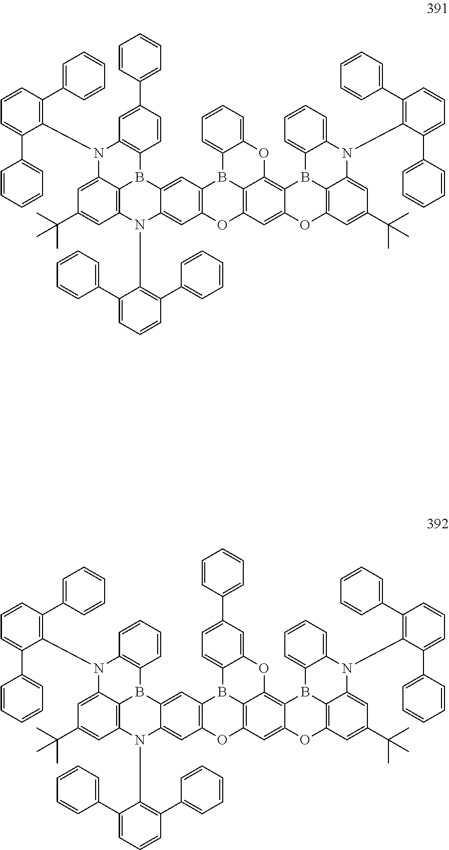 [SMILES: CC(C)(C)c1cc2c3c(c1)N(c1c(-c4ccccc4)cccc1-c1ccccc1)c1ccccc1B3c1c(cc3c4c1Oc1ccccc1B4c1cc4c(cc1O3)N(c1c(-c3ccccc3)cccc1-c1ccccc1)c1cc(C(C)(C)C)cc3c1B4c1ccc(-c4ccccc4)cc1N3c1c(-c3ccccc3)cccc1-c1ccccc1)O2 ; CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1O3)N(c1c(-c3ccccc3)cccc1-c1ccccc1)c1cc(C(C)(C)C)cc3c1B4c1ccccc1N3c1c(-c3ccccc3)cccc1-c1ccccc1)O2] 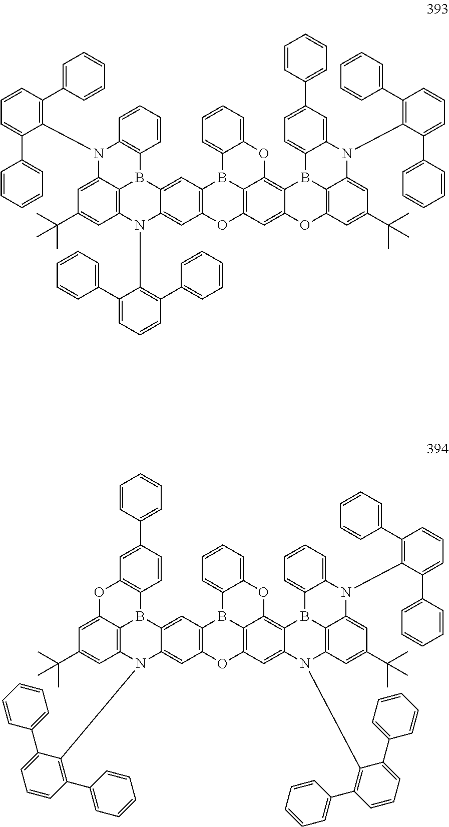 [SMILES: CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1O3)N(c1c(-c3ccccc3)cccc1-c1ccccc1)c1cc(C(C)(C)C)cc3c1B4c1ccccc1N3c1c(-c3ccccc3)cccc1-c1ccccc1)O2 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)O4] 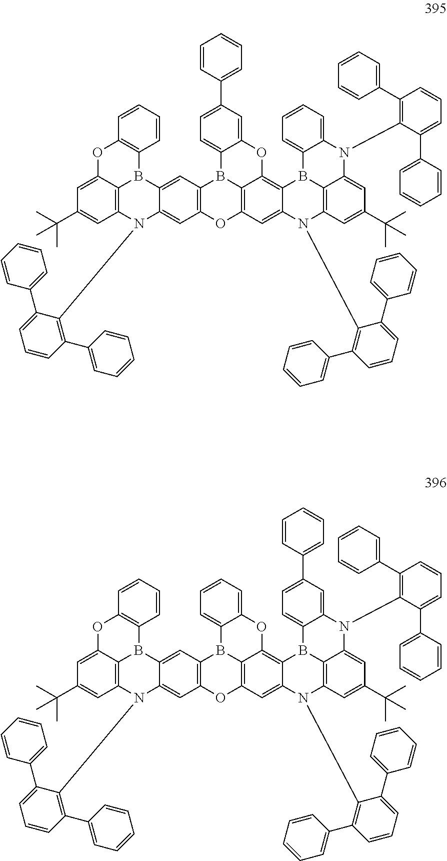 [SMILES: CC(C)(C)c1cc2c3c(c1)N(c1c(-c4ccccc4)cccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)N1c1c(-c2ccccc2)cccc1-c1ccccc1)O4] 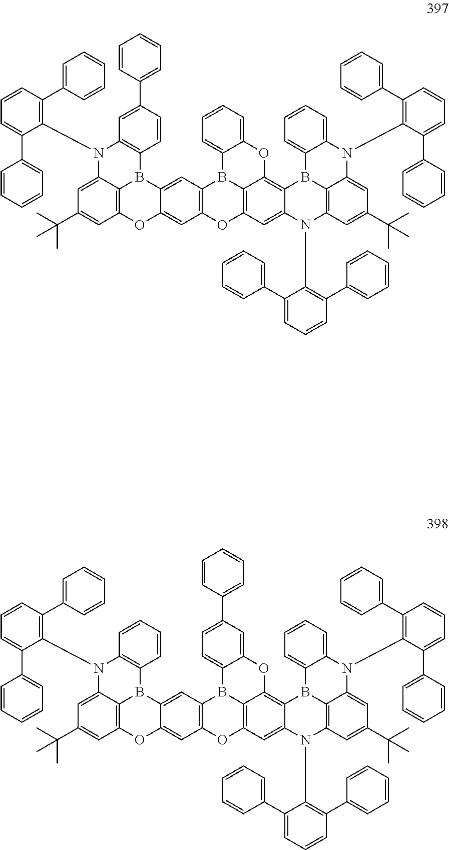 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccccc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)N2c1c(-c2ccccc2)cccc1-c1ccccc1] 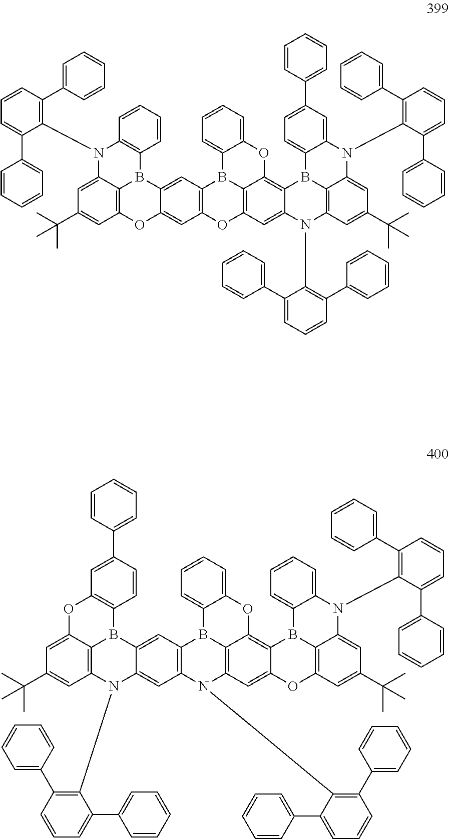 [SMILES: CC(C)(C)c1cc2c3c(c1)N(c1c(-c4ccccc4)cccc1-c1ccccc1)c1ccccc1B3c1cc3c(cc1O2)Oc1cc2c(c4c1B3c1ccccc1O4)B1c3ccc(-c4ccccc4)cc3N(c3c(-c4ccccc4)cccc3-c3ccccc3)c3cc(C(C)(C)C)cc(c31)N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c3c(cc(c21)N4c1c(-c2ccccc2)cccc1-c1ccccc1)Oc1cc(C(C)(C)C)cc2c1B3c1ccccc1N2c1c(-c2ccccc2)cccc1-c1ccccc1] 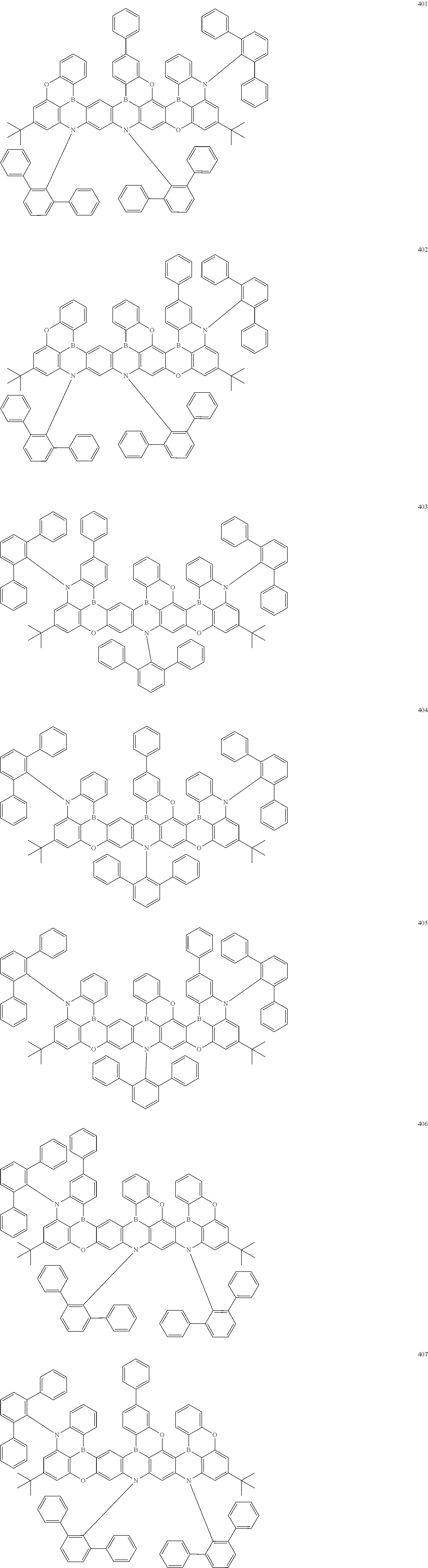 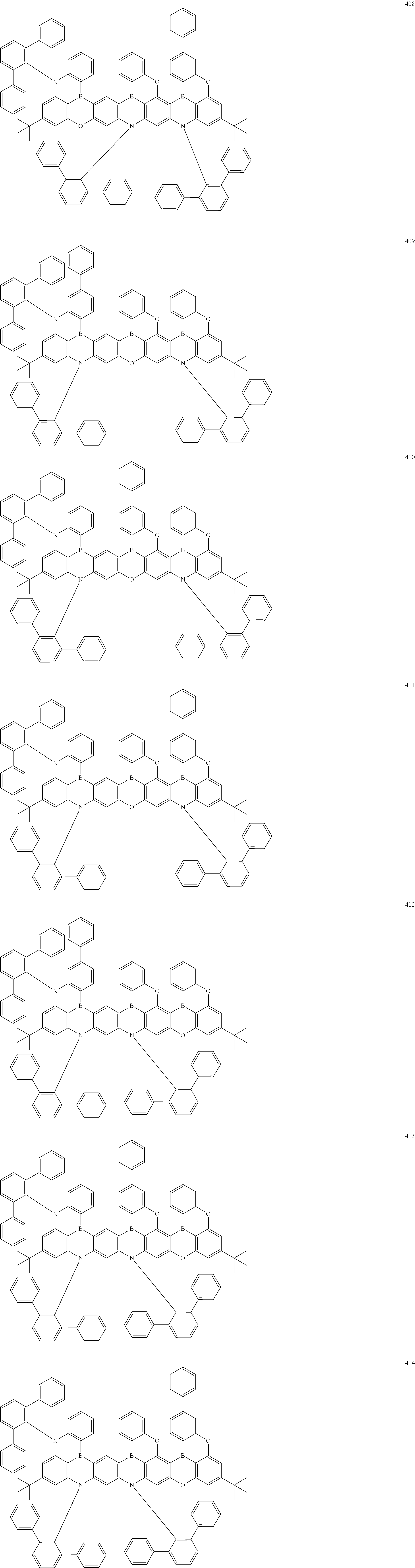 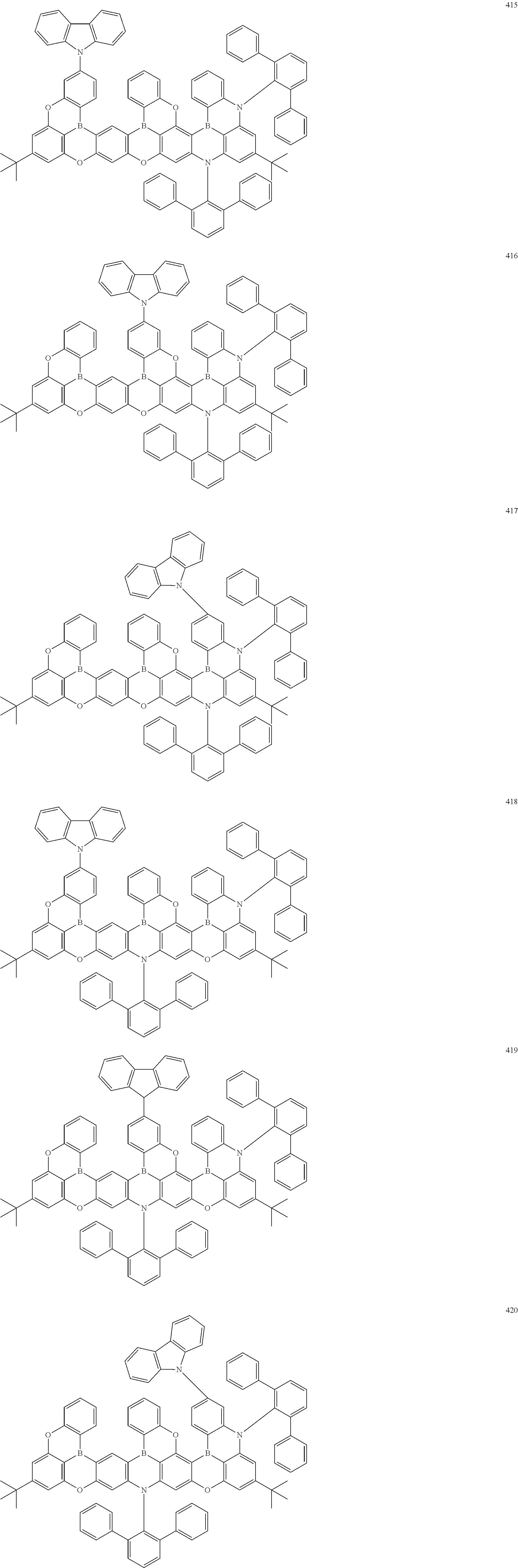 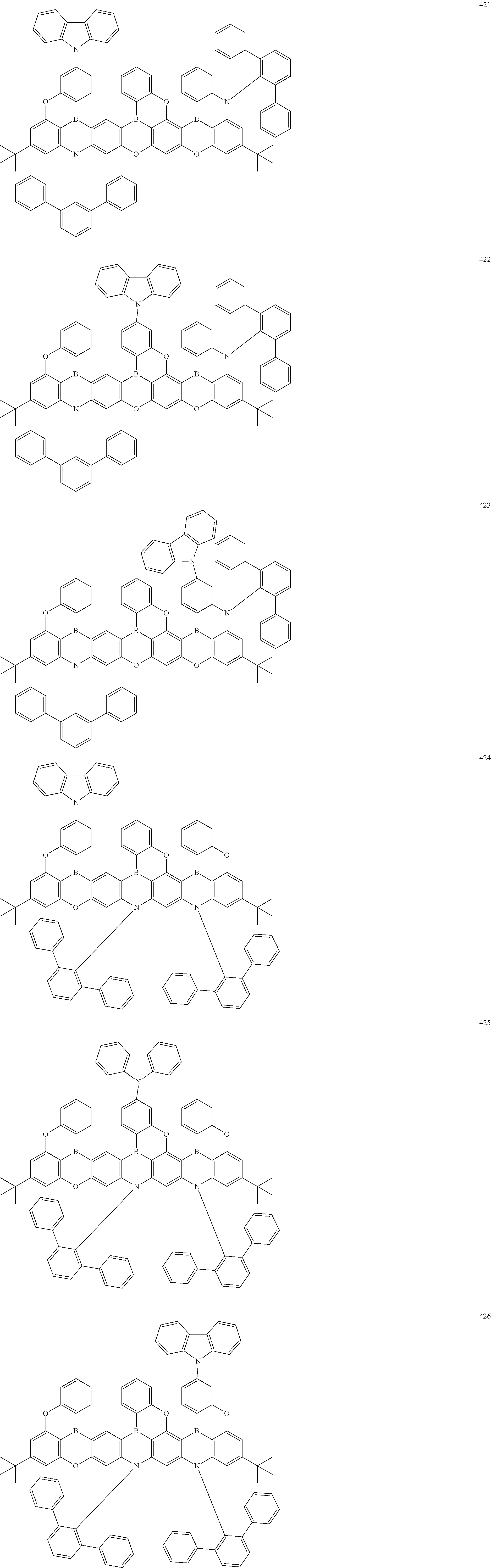 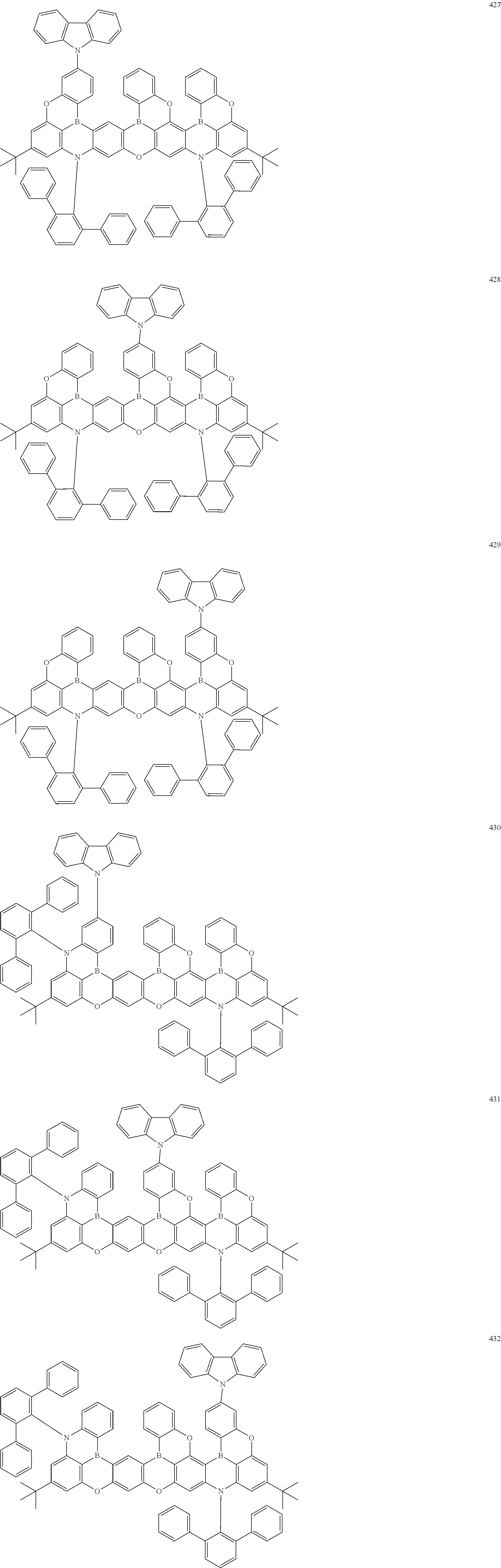 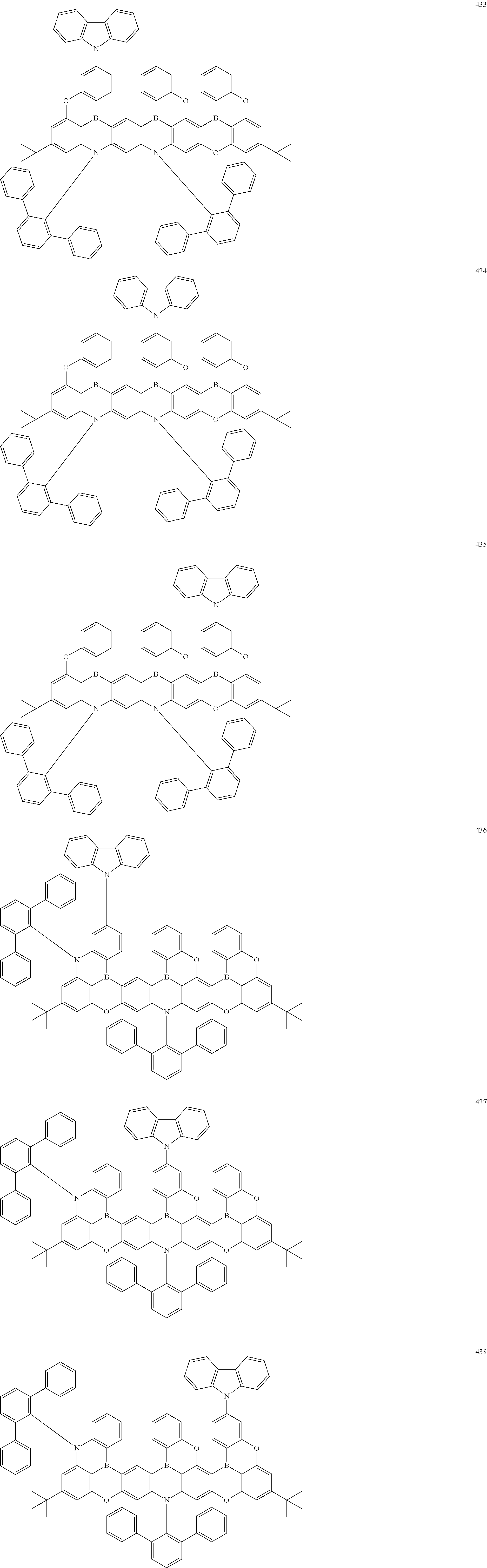 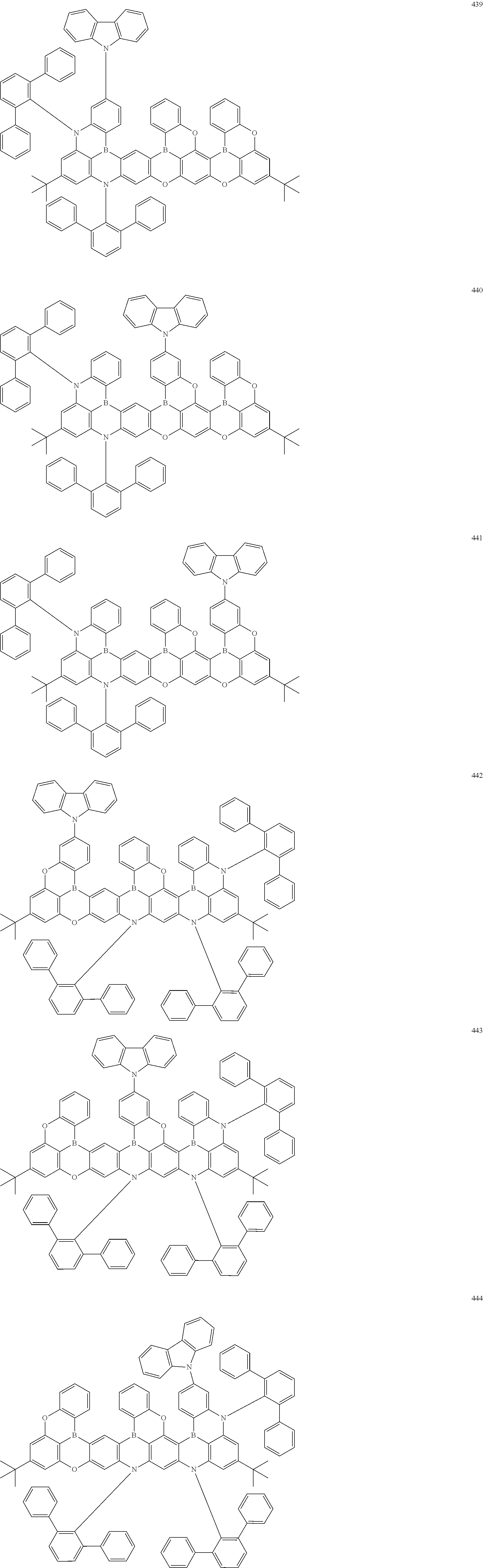 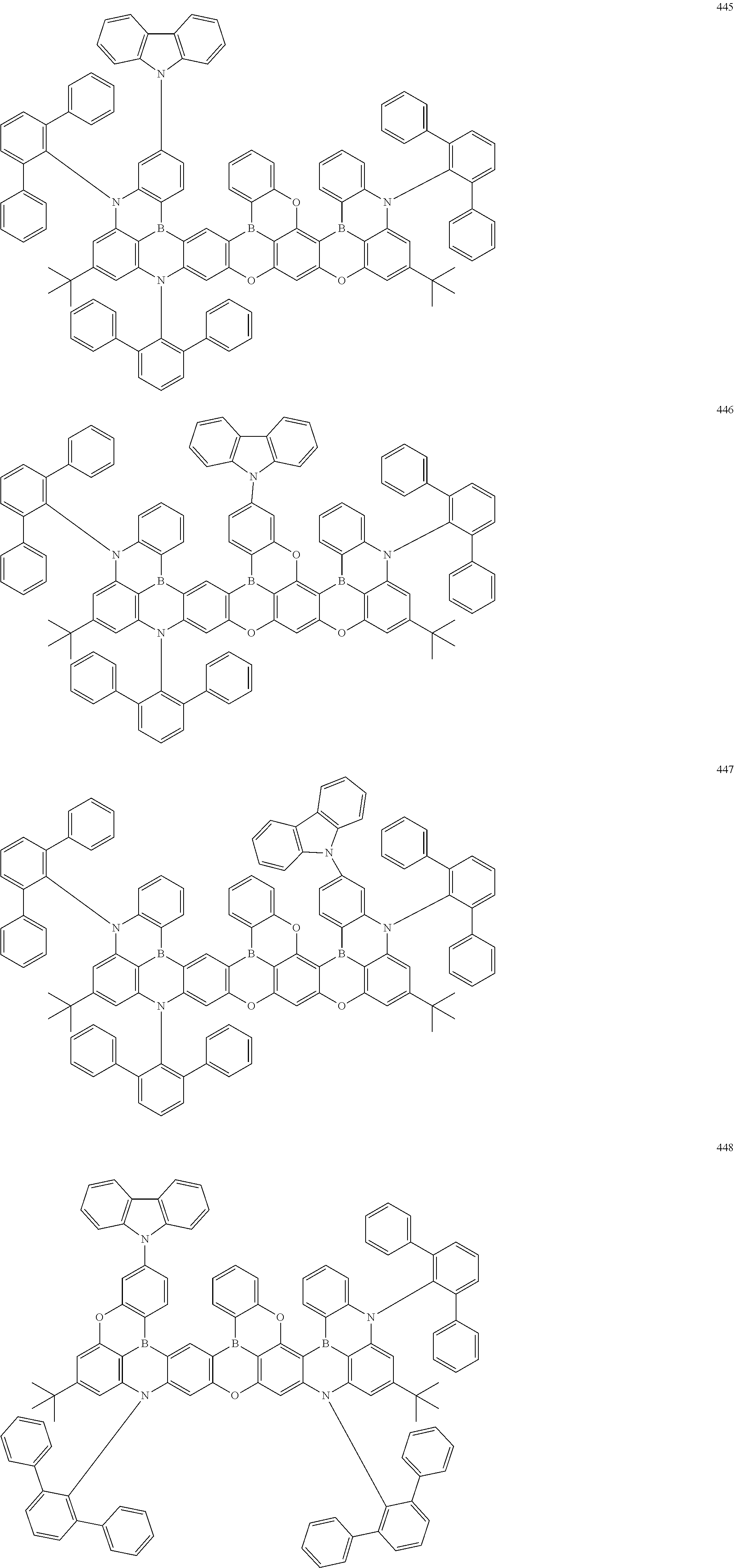 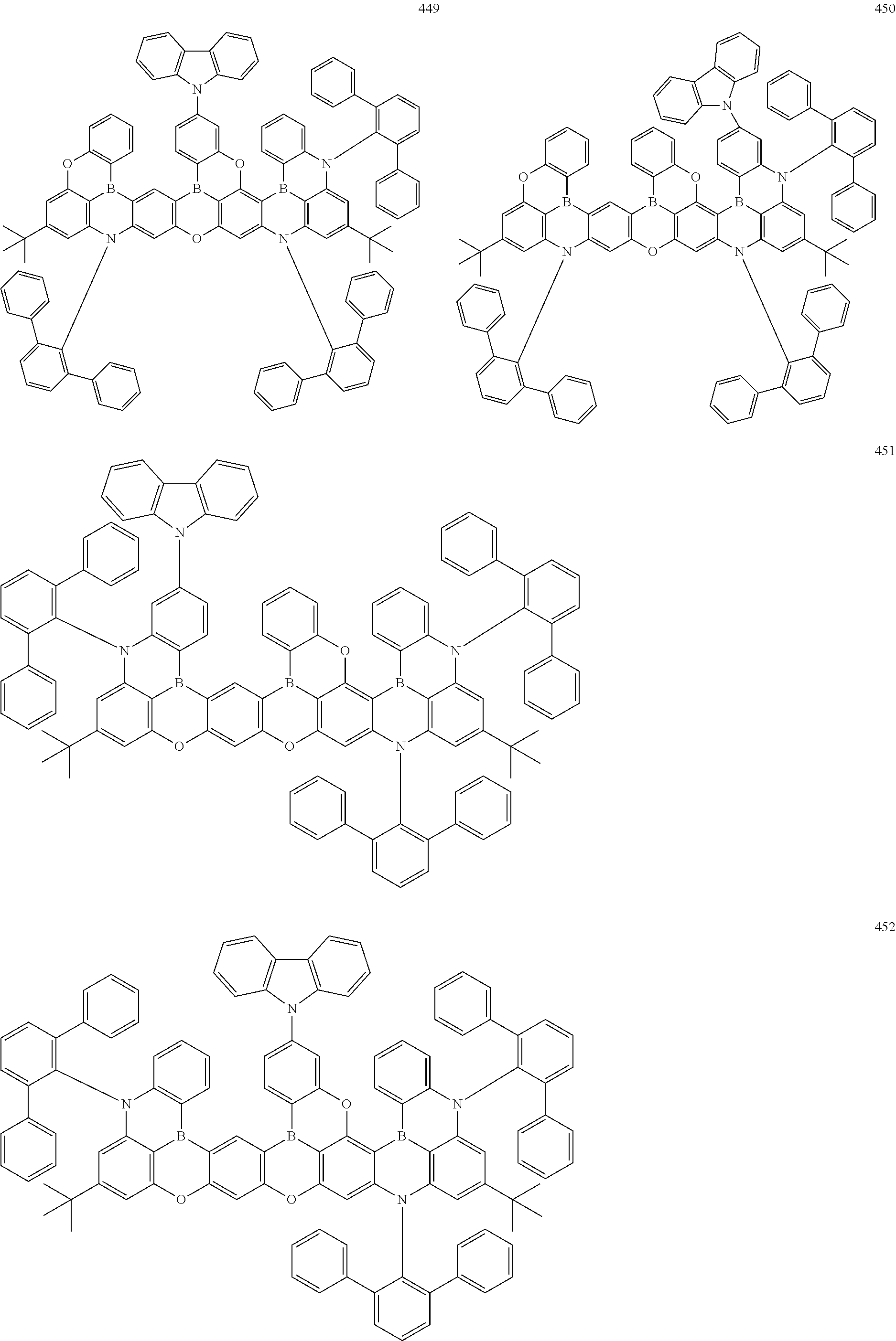 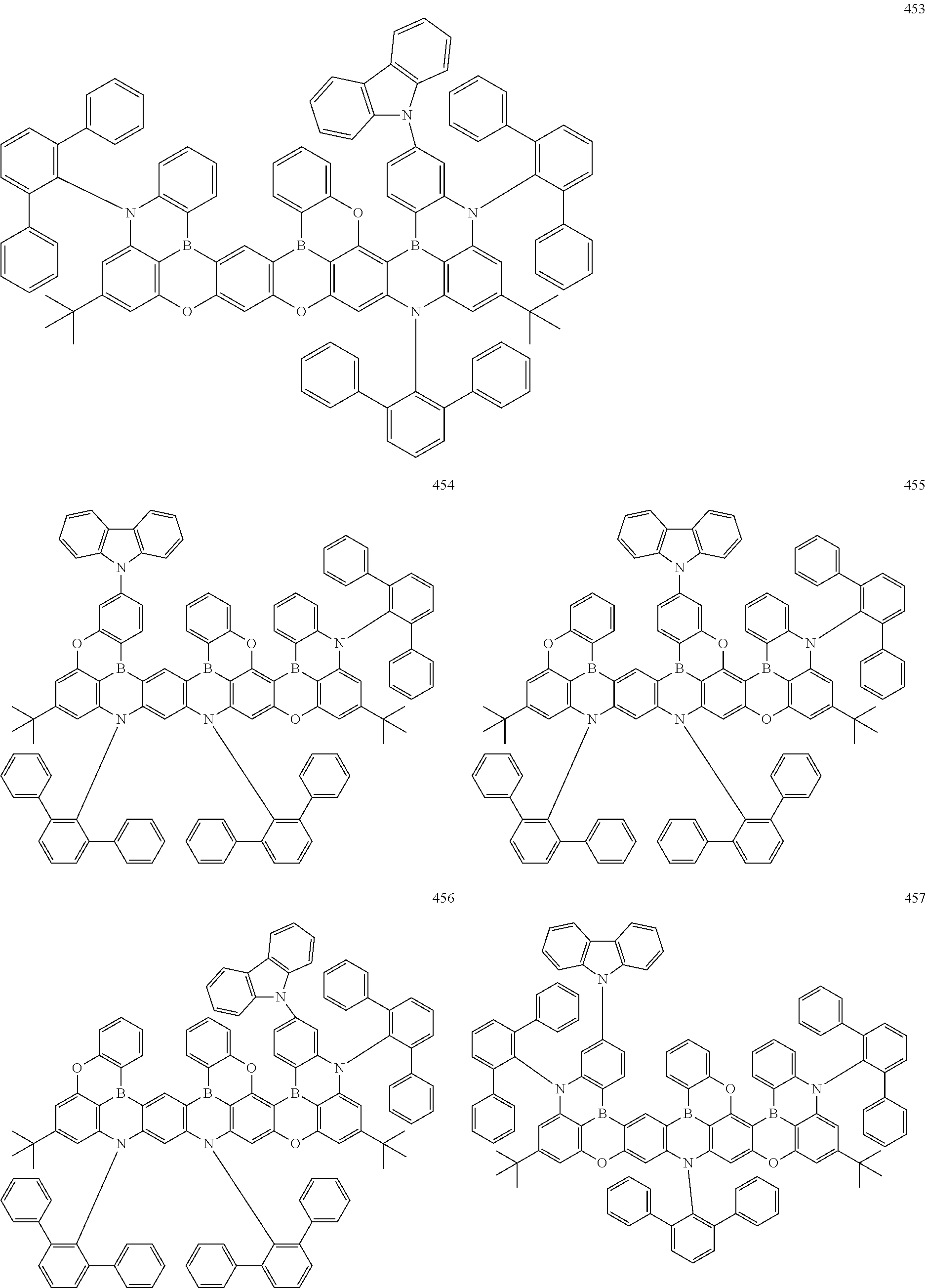 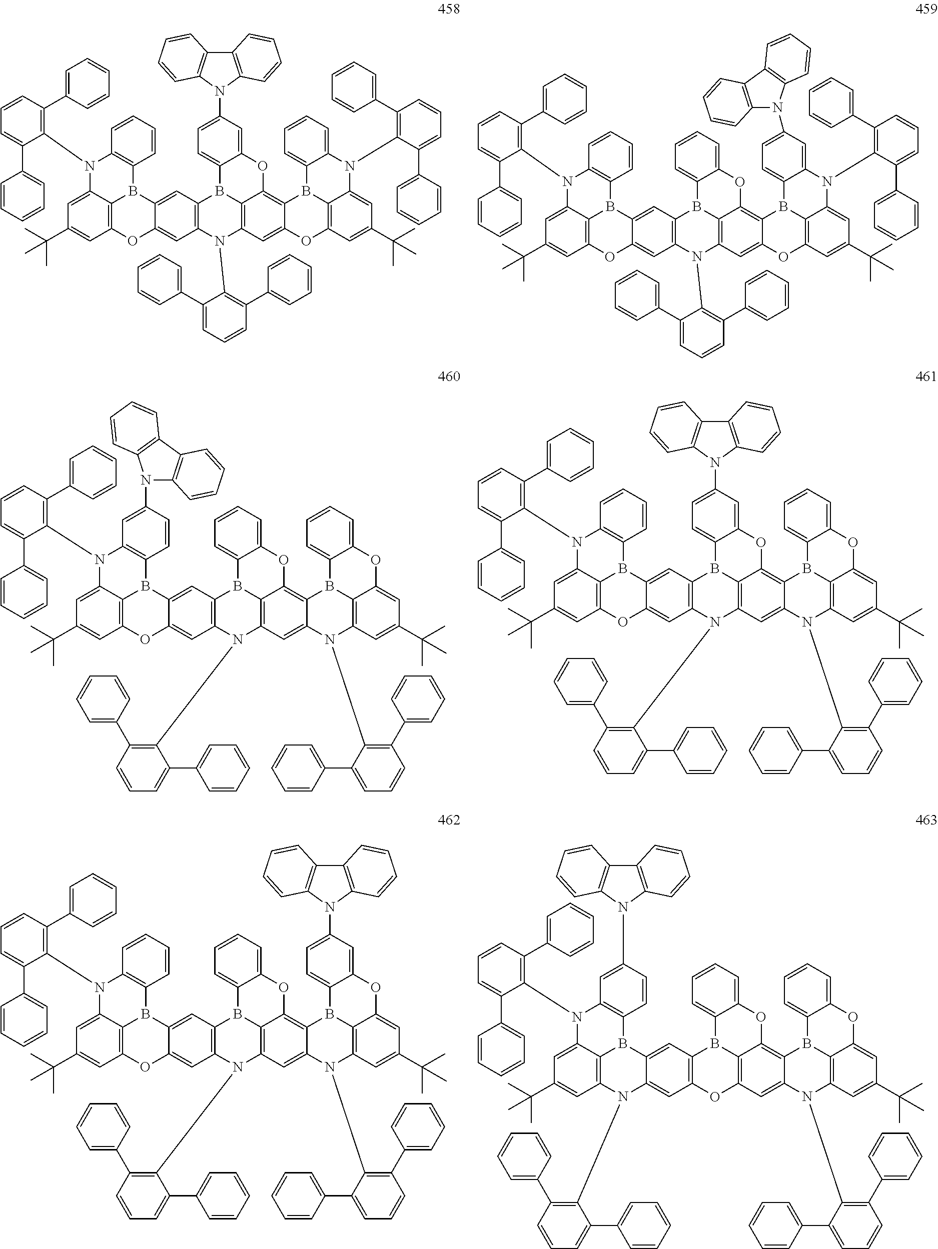 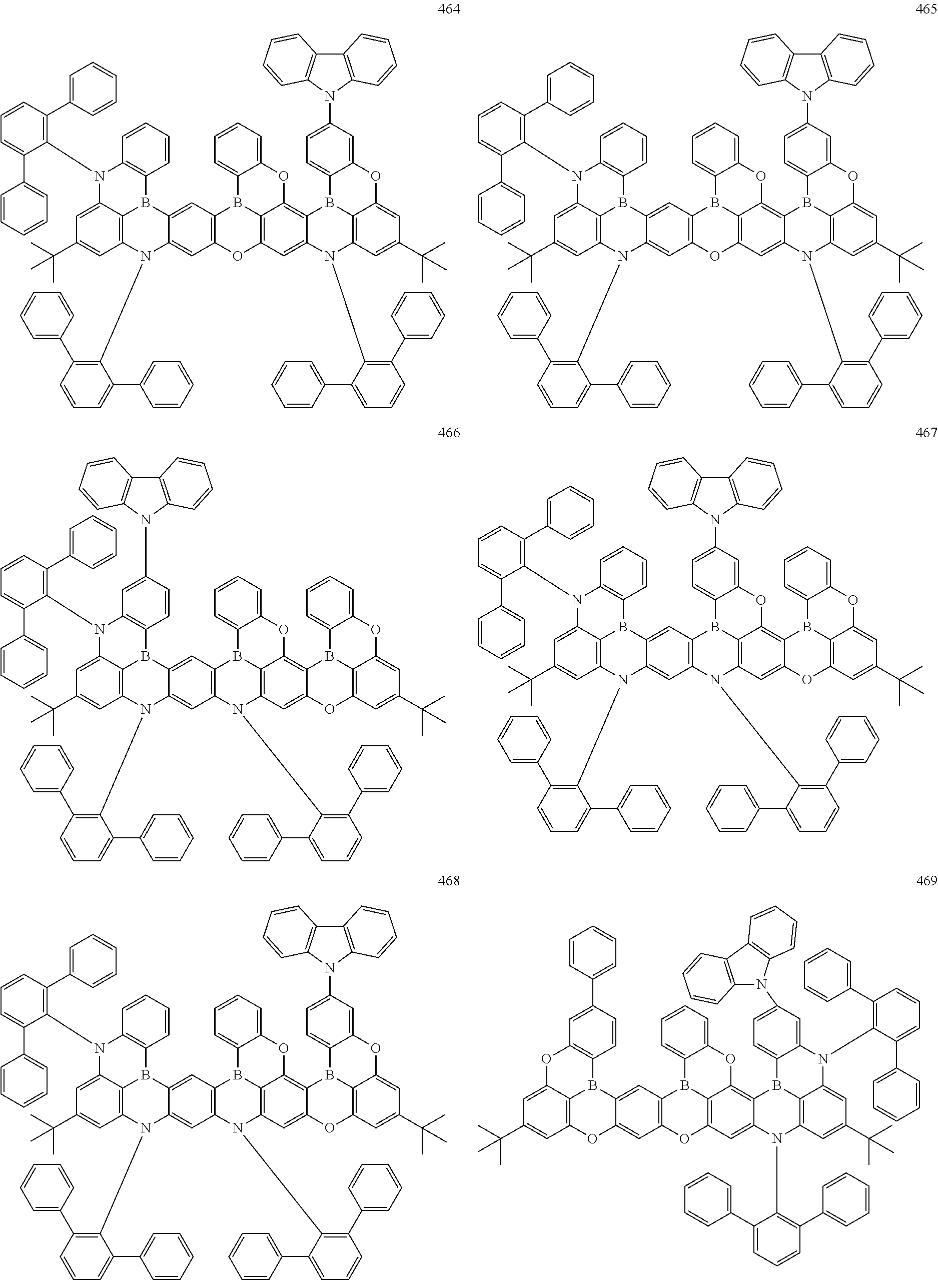 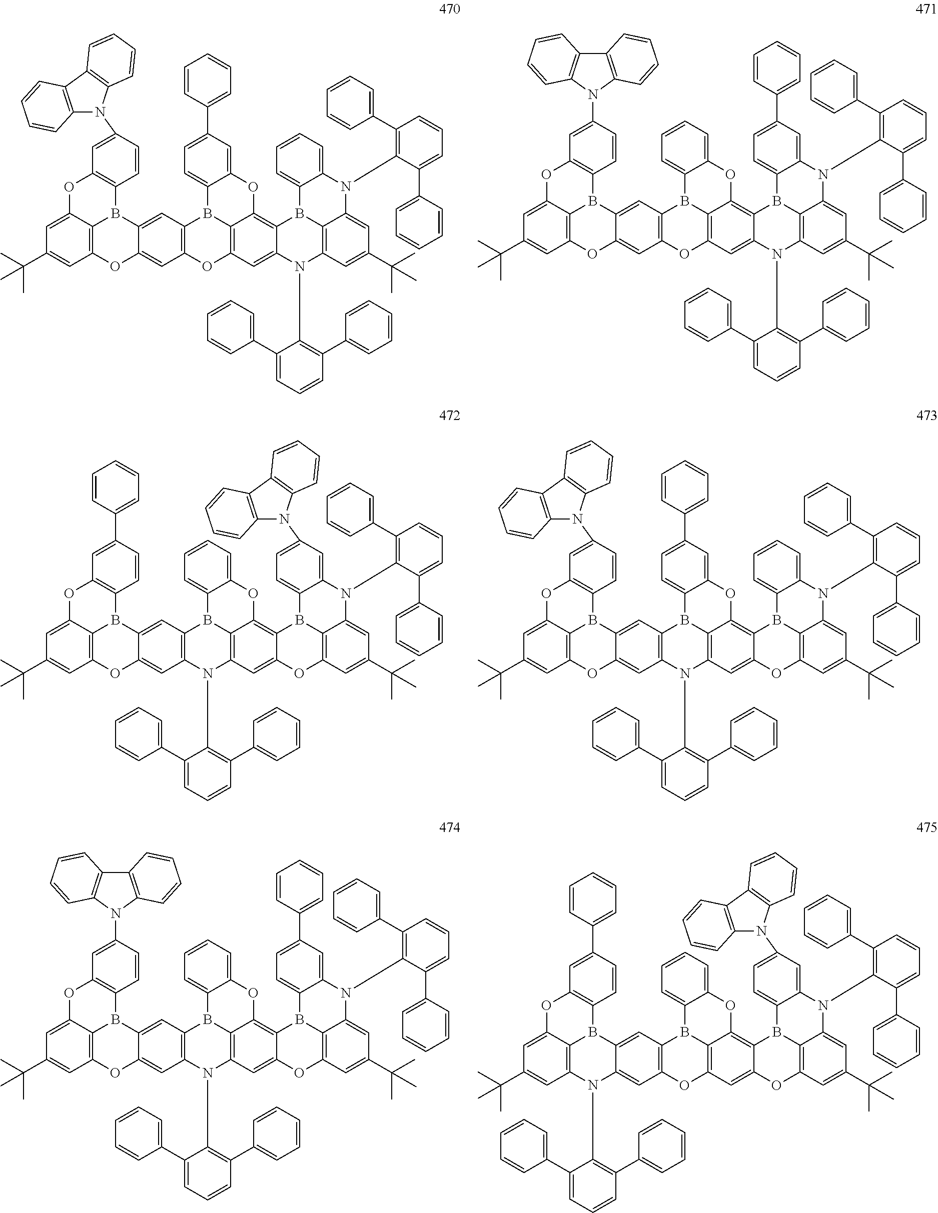 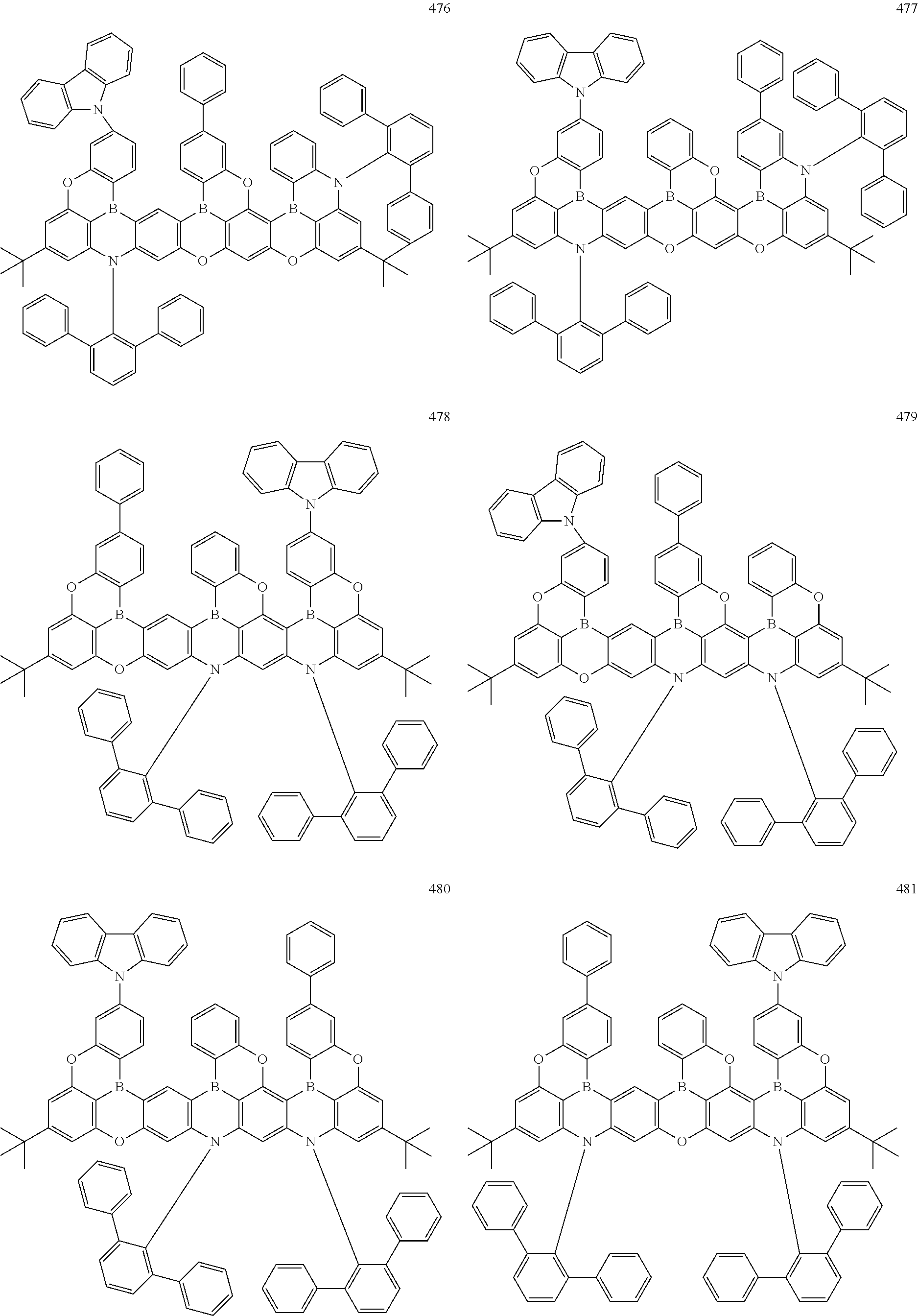 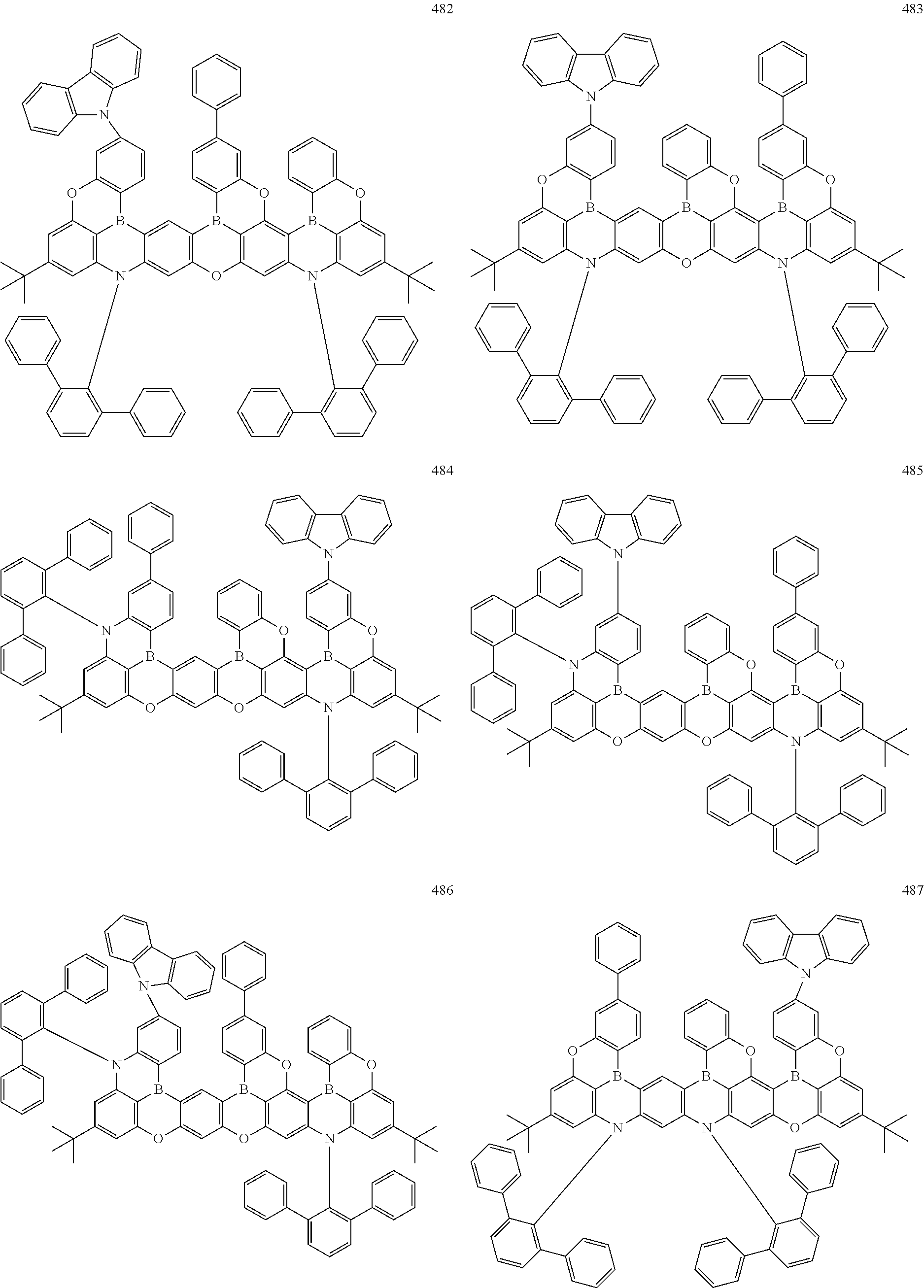 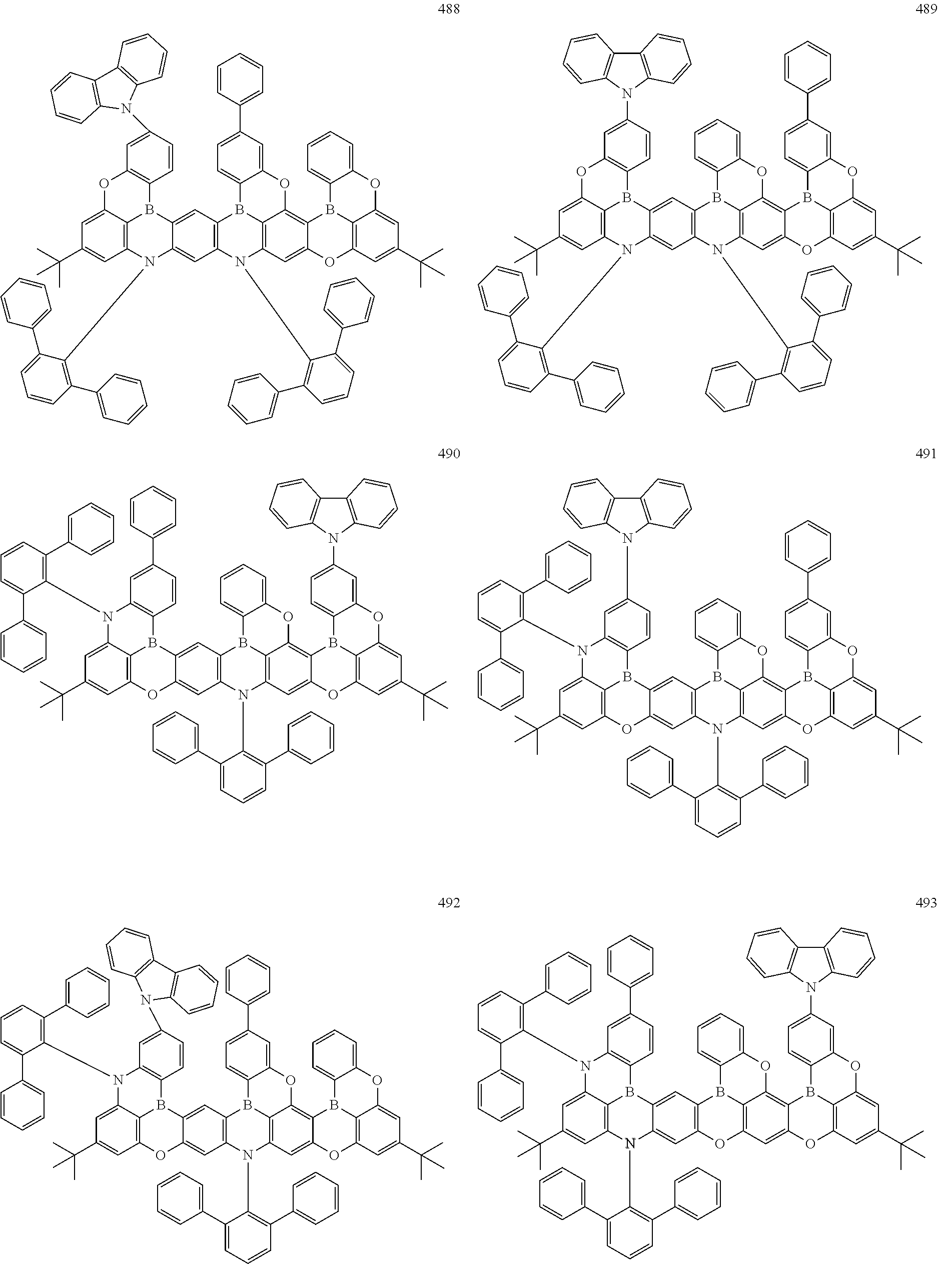 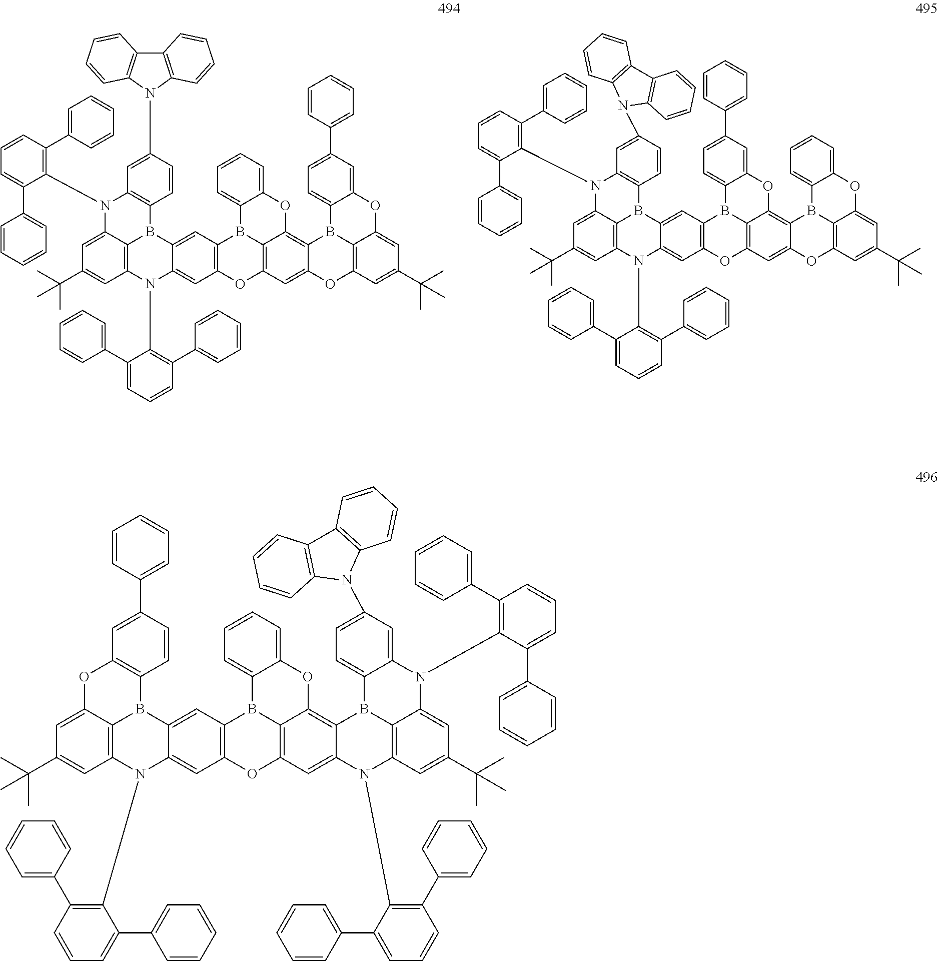 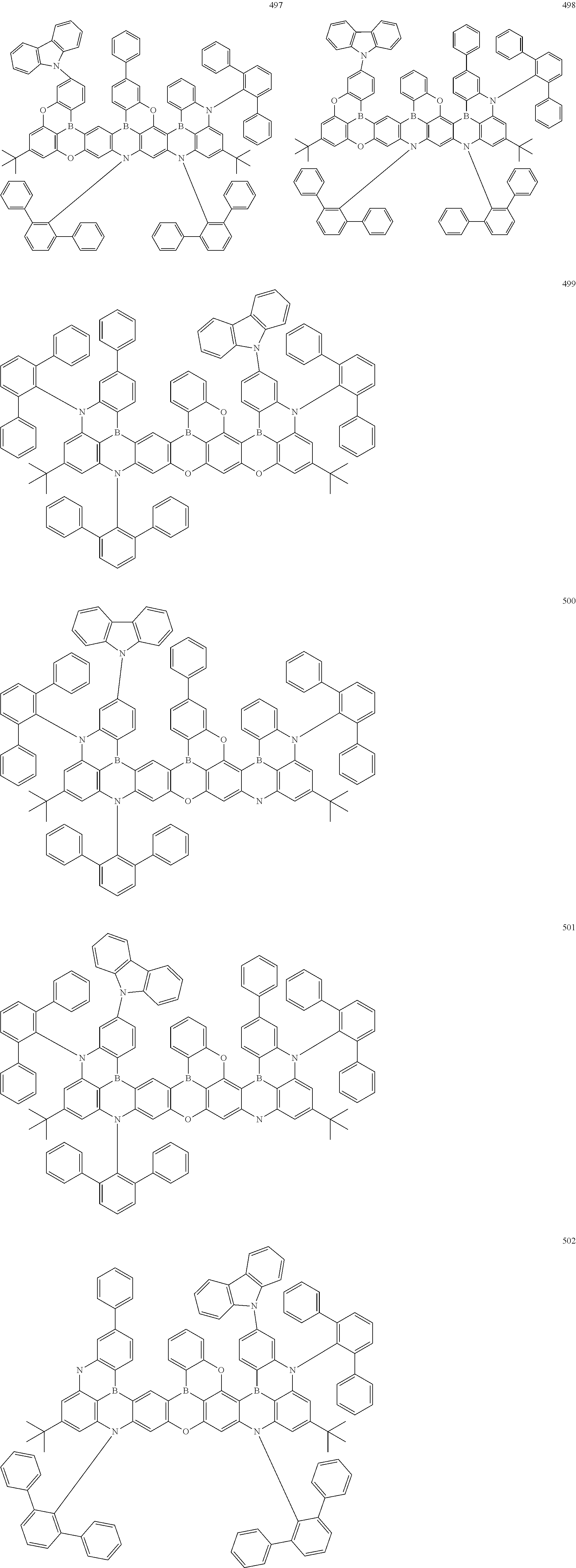 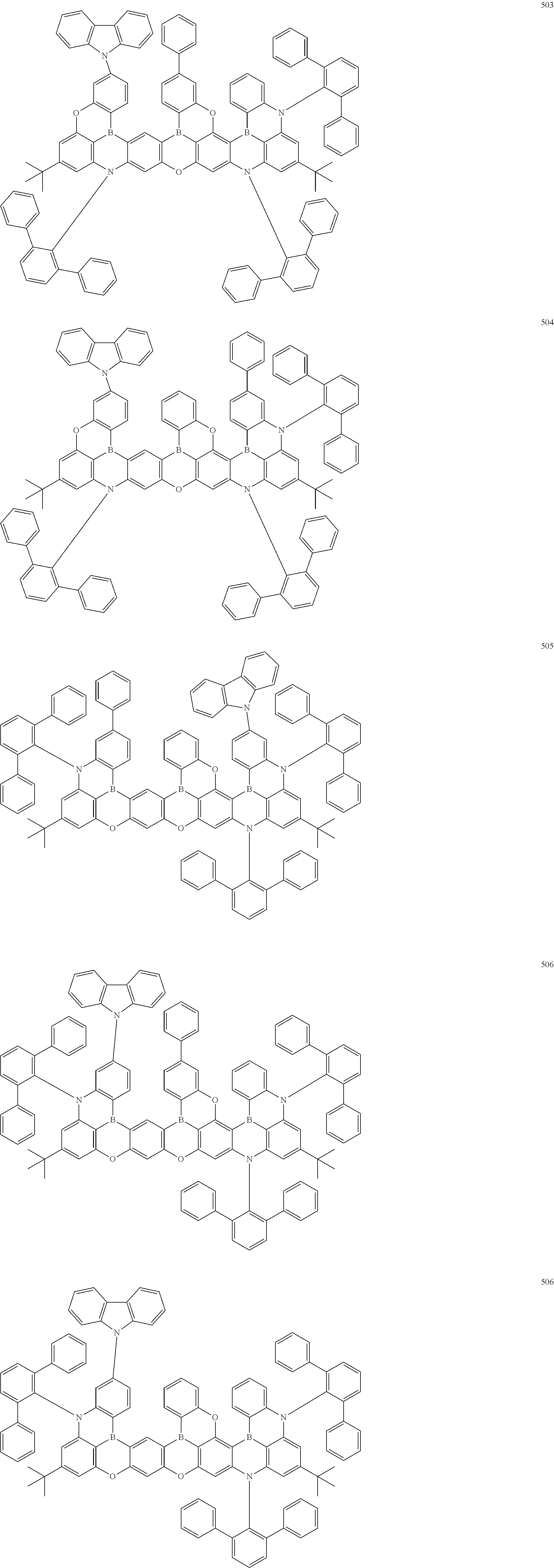 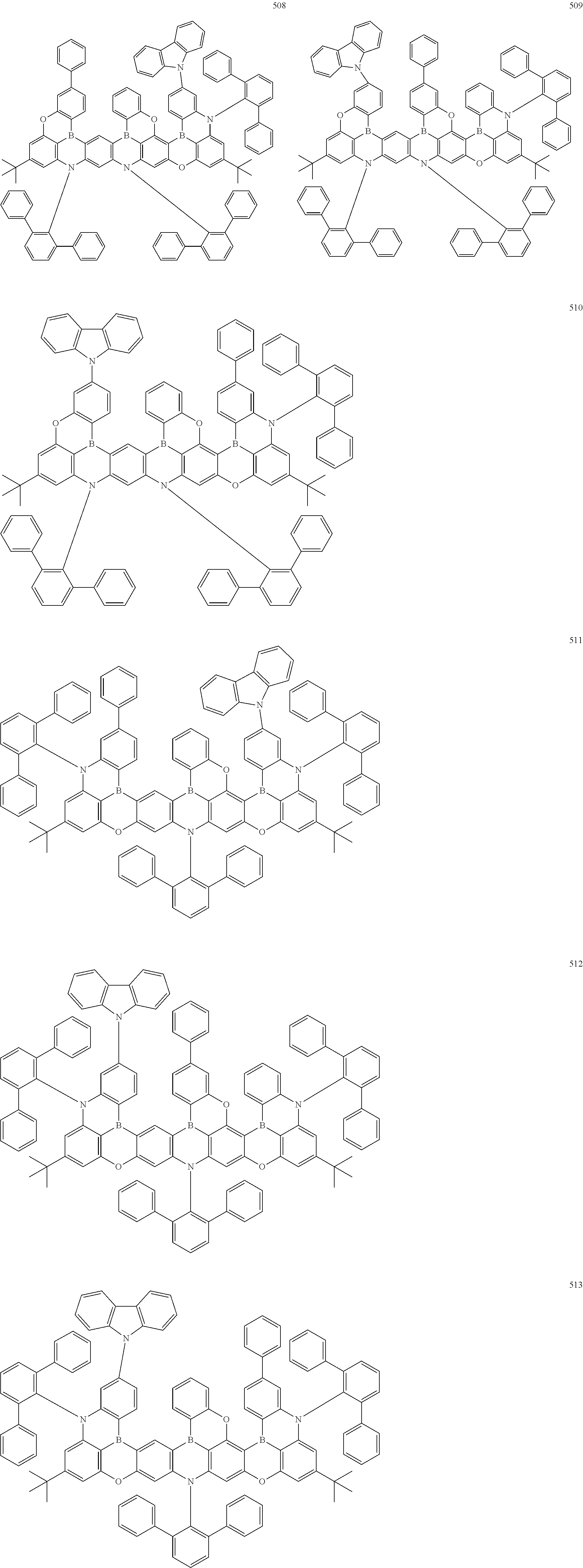 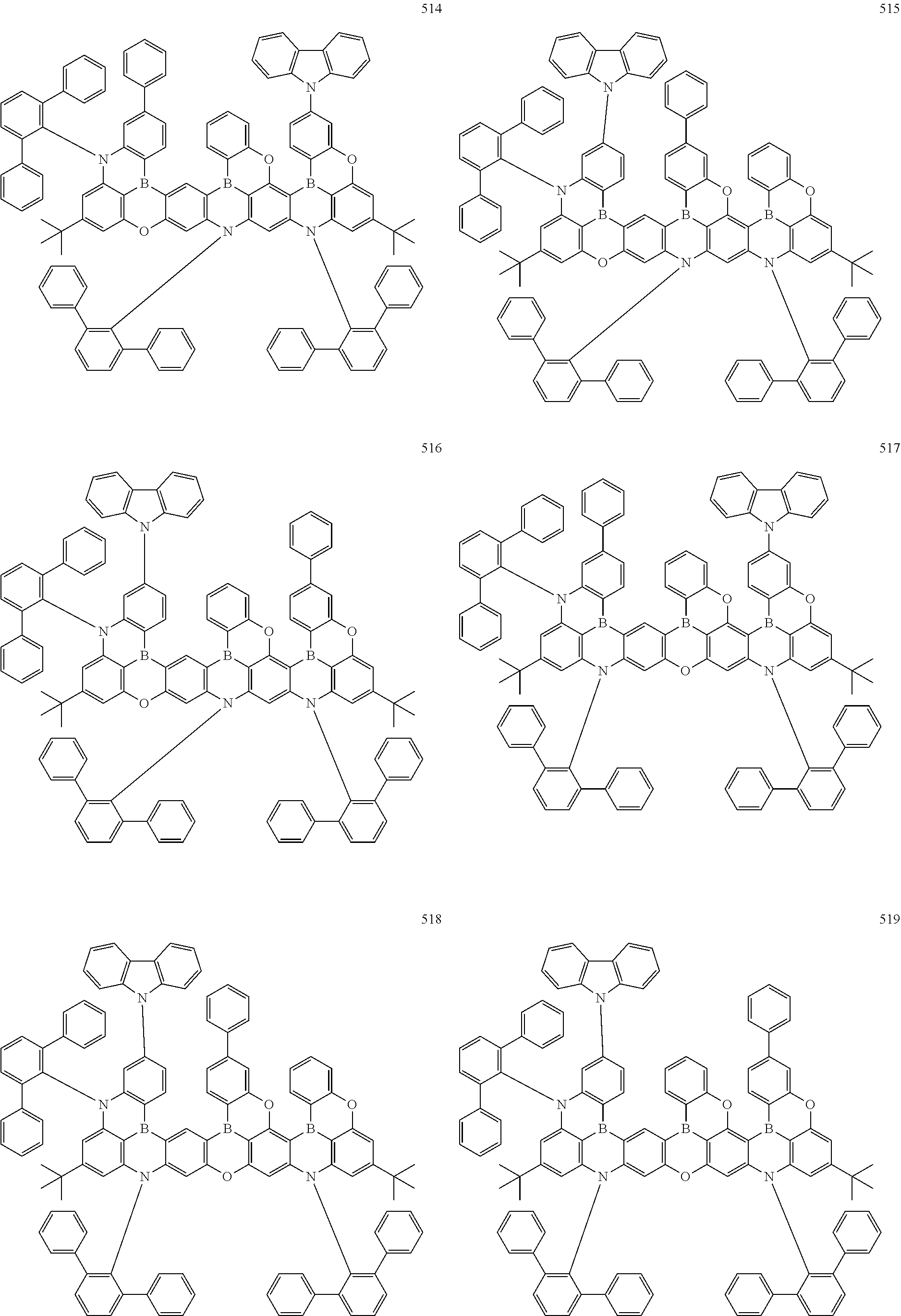 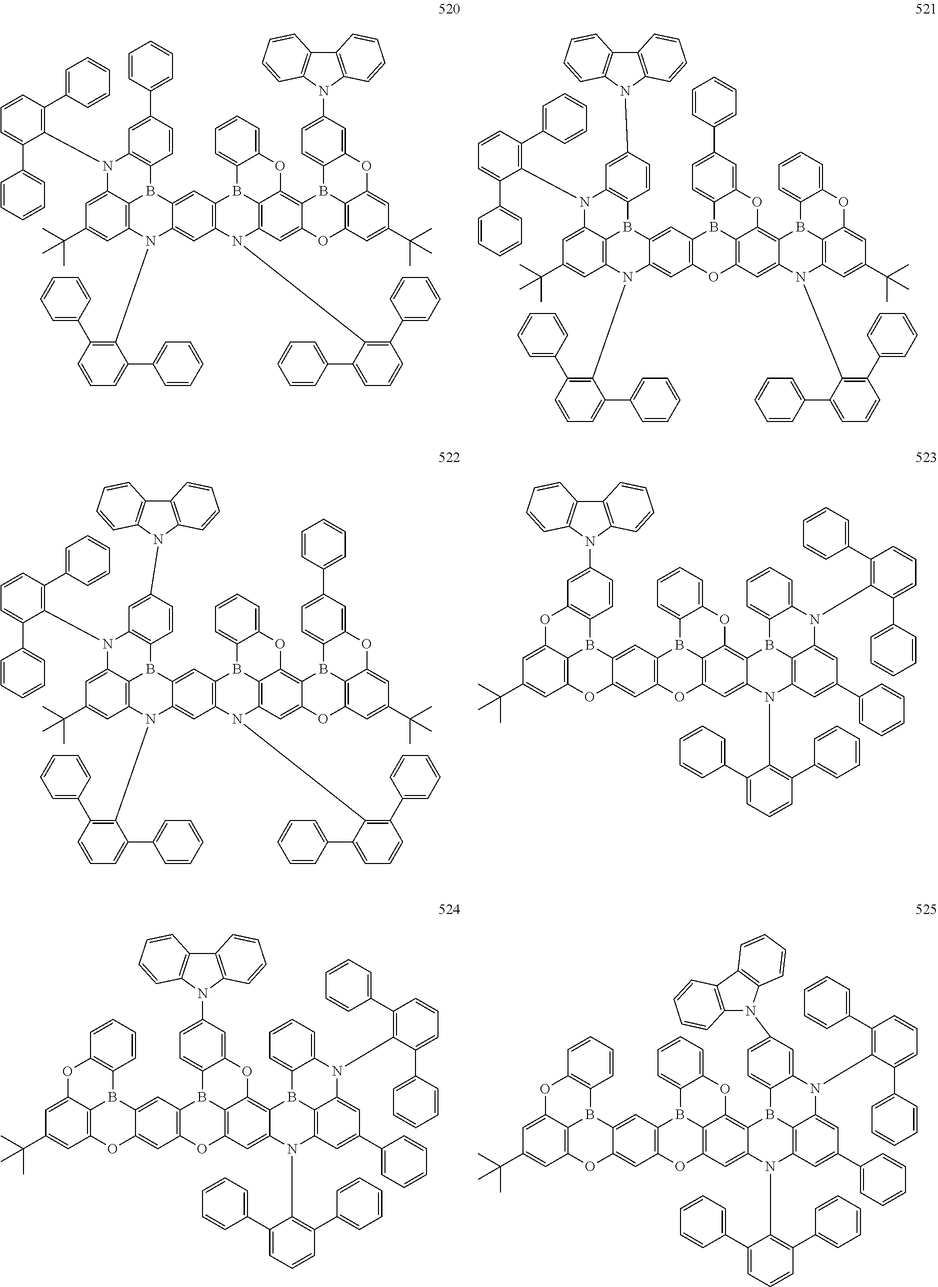 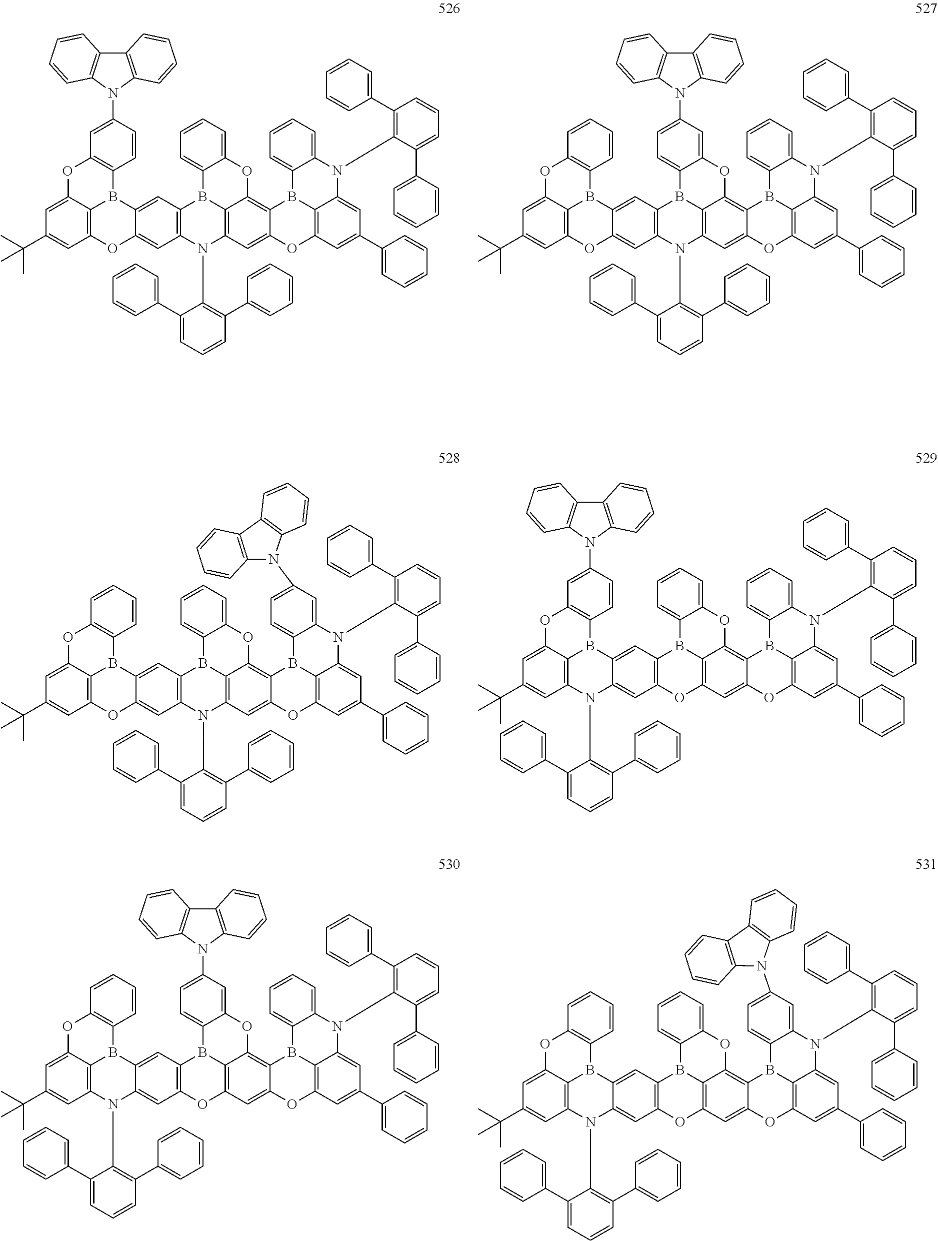 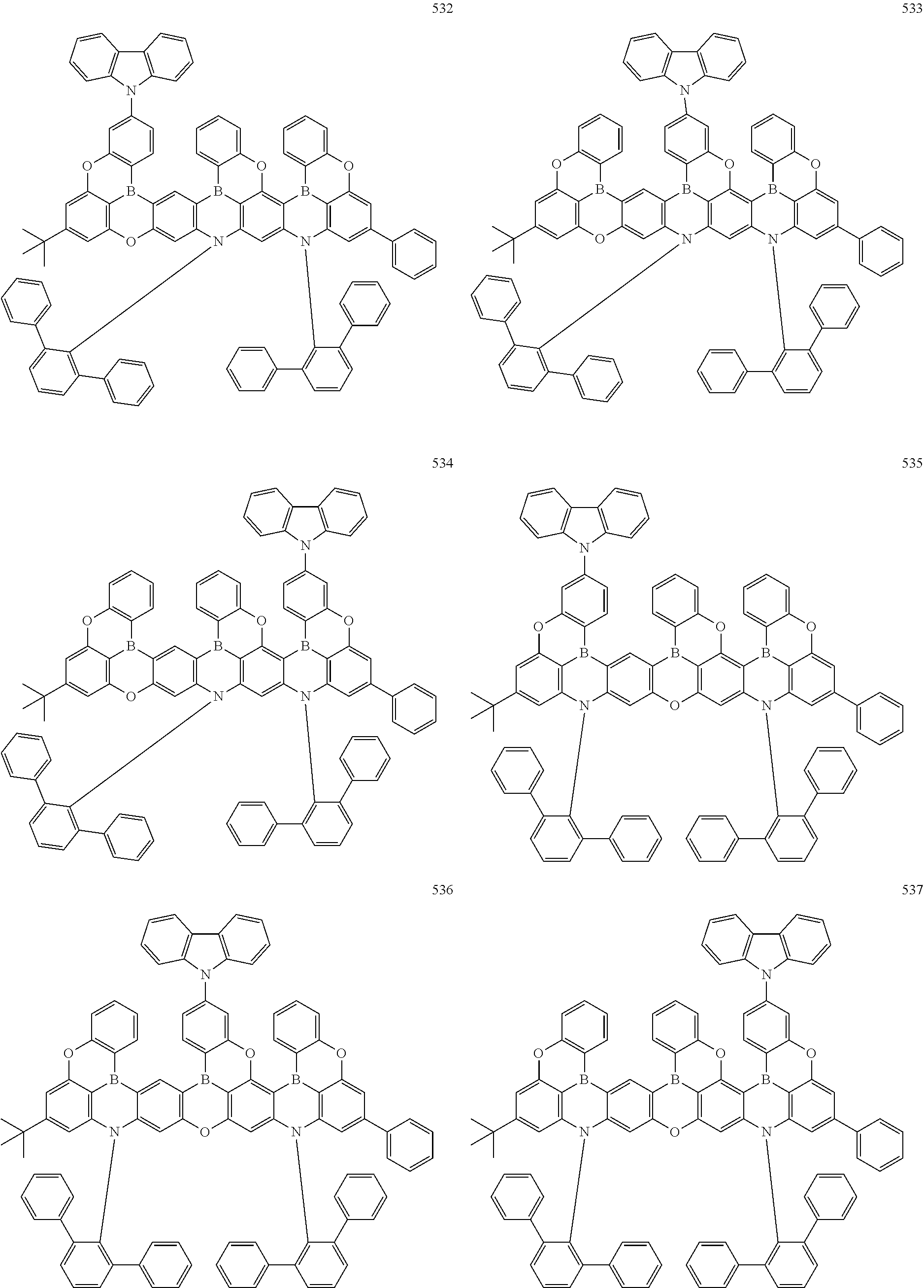 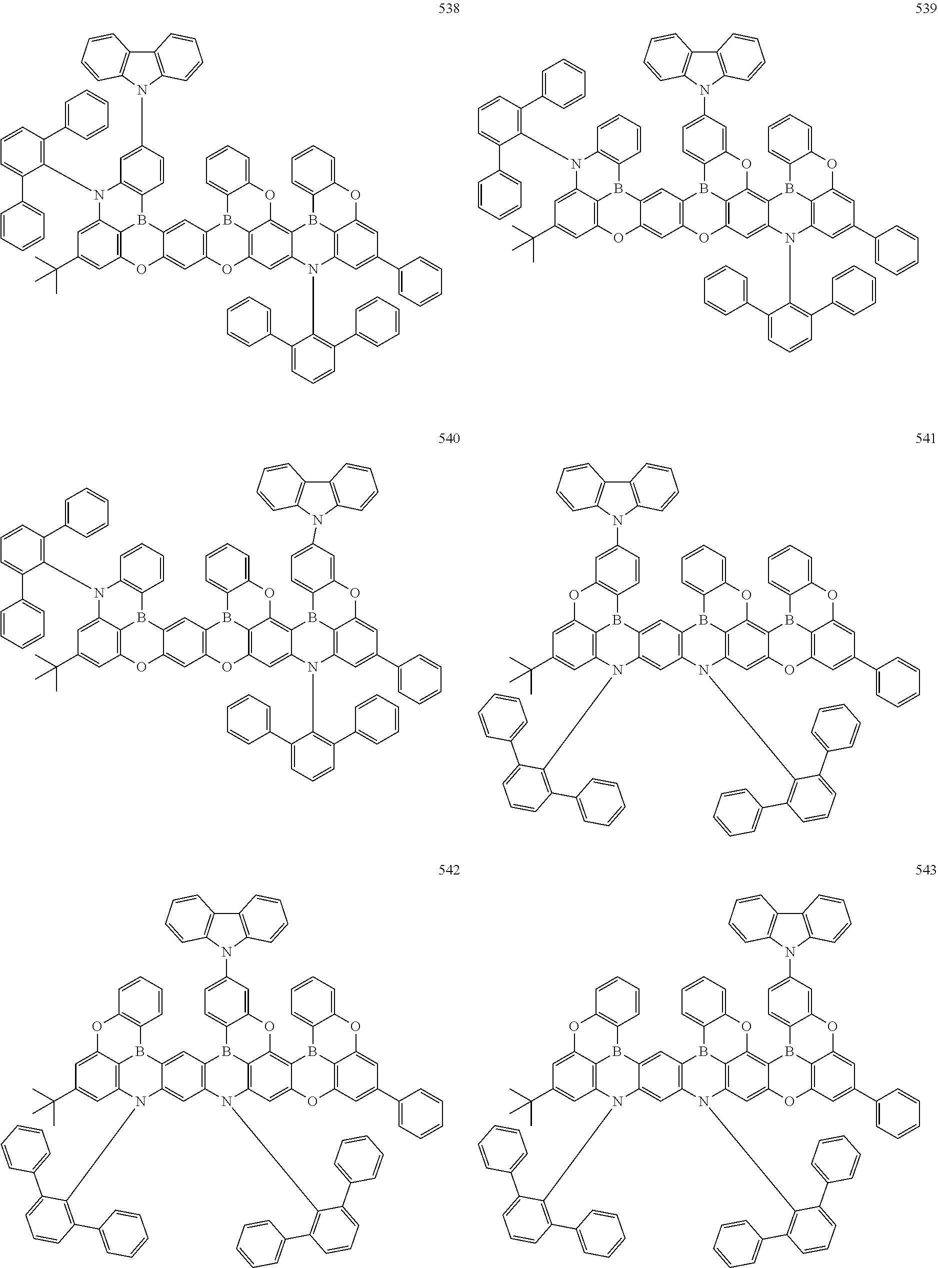 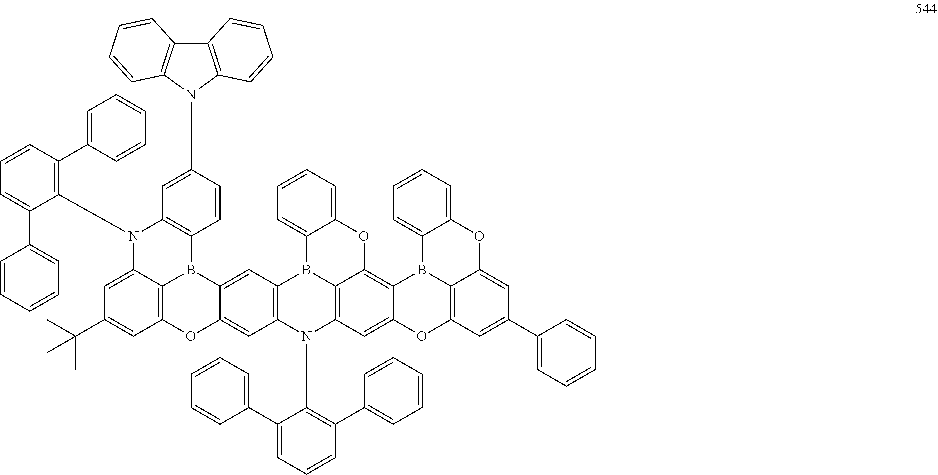 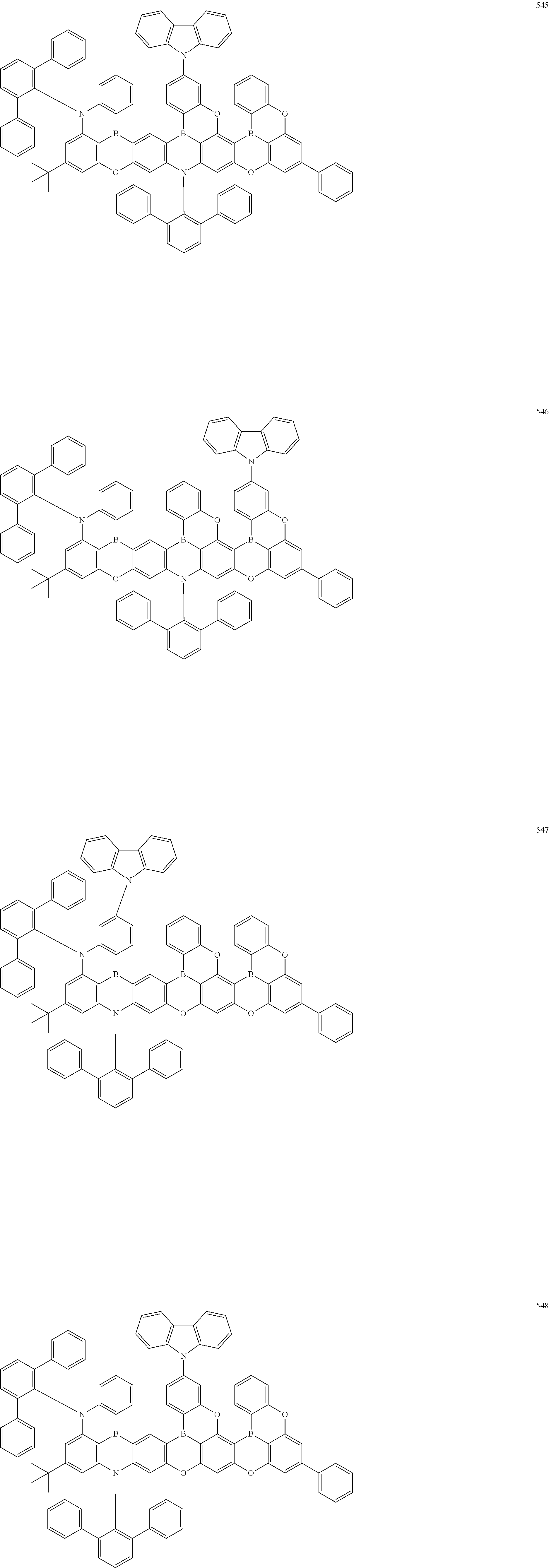 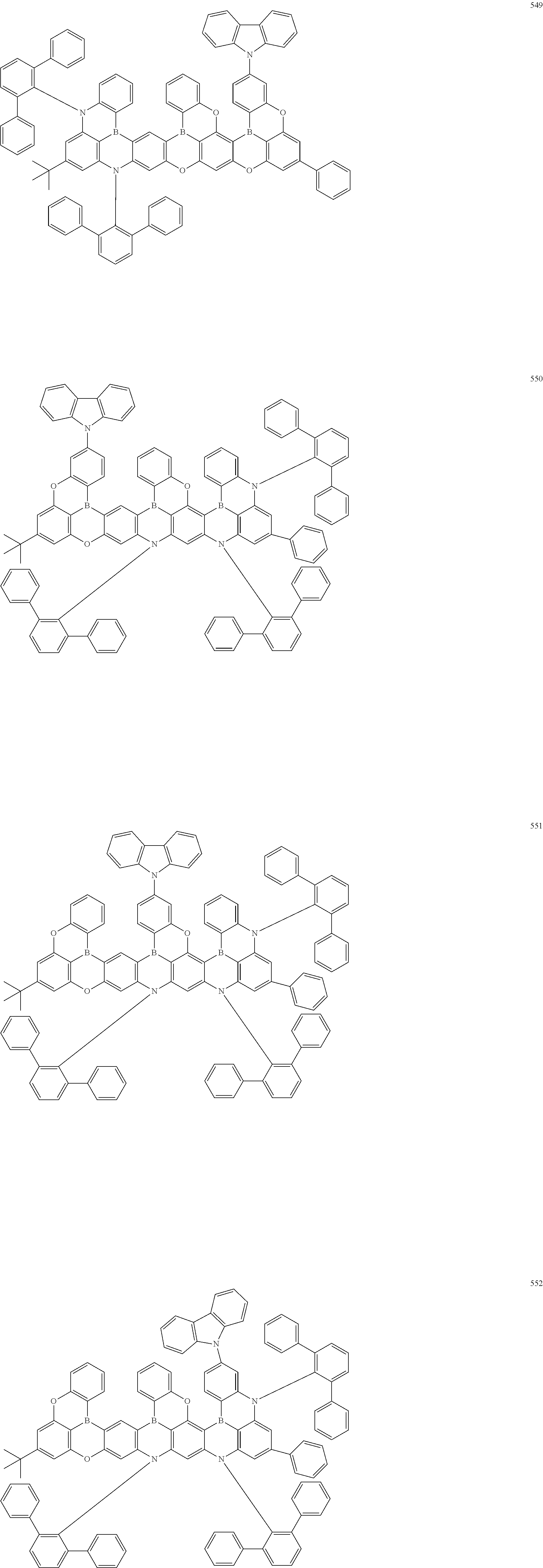 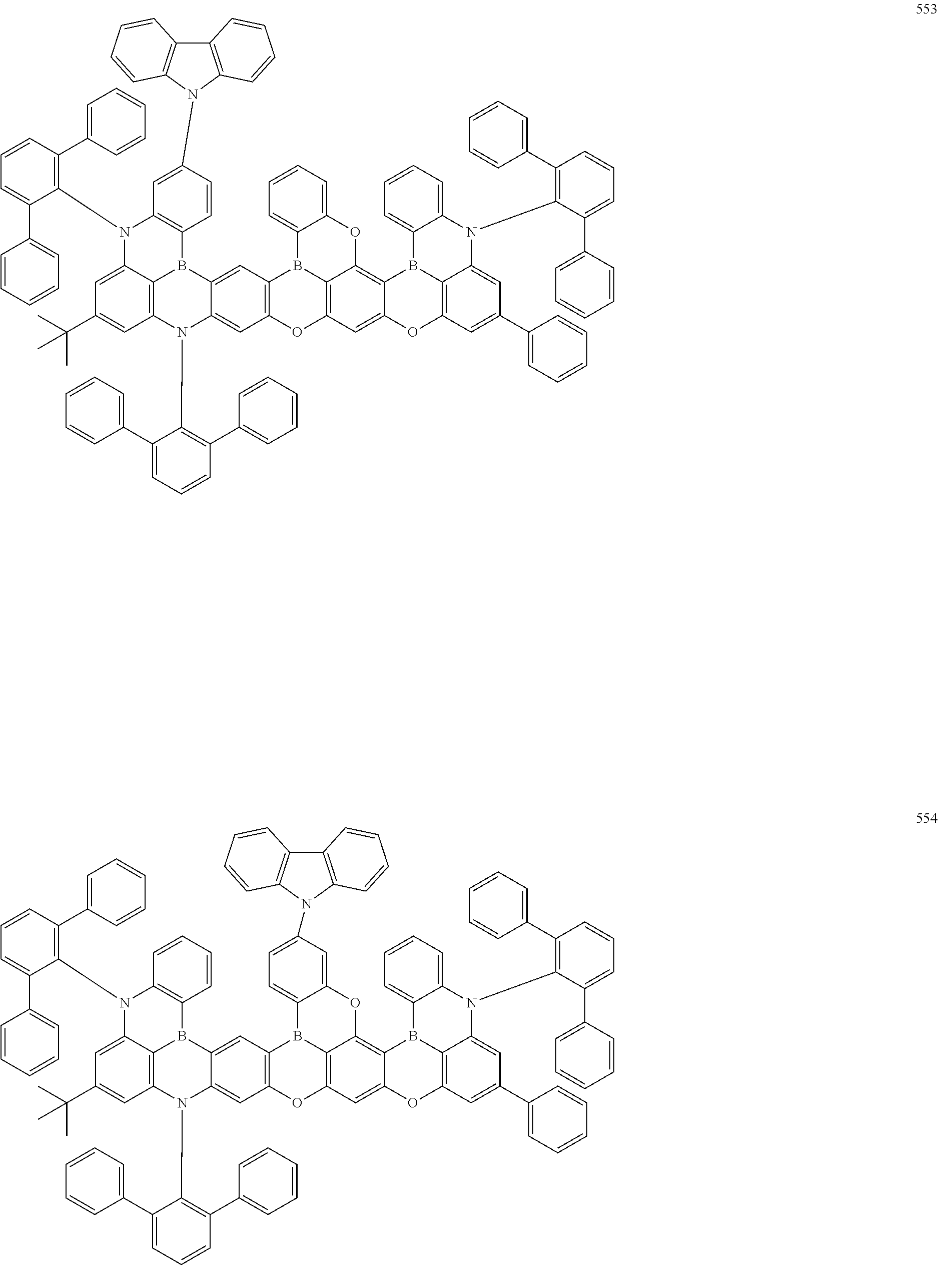 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)B1c2ccccc2Oc2c1c(cc1c2B2c3ccccc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccc(-n3c5ccccc5c5ccccc53)cc2Oc2c1c(cc1c2B2c3ccccc3N(c3c(-c5ccccc5)cccc3-c3ccccc3)c3cc(-c5ccccc5)cc(c32)O1)O4] 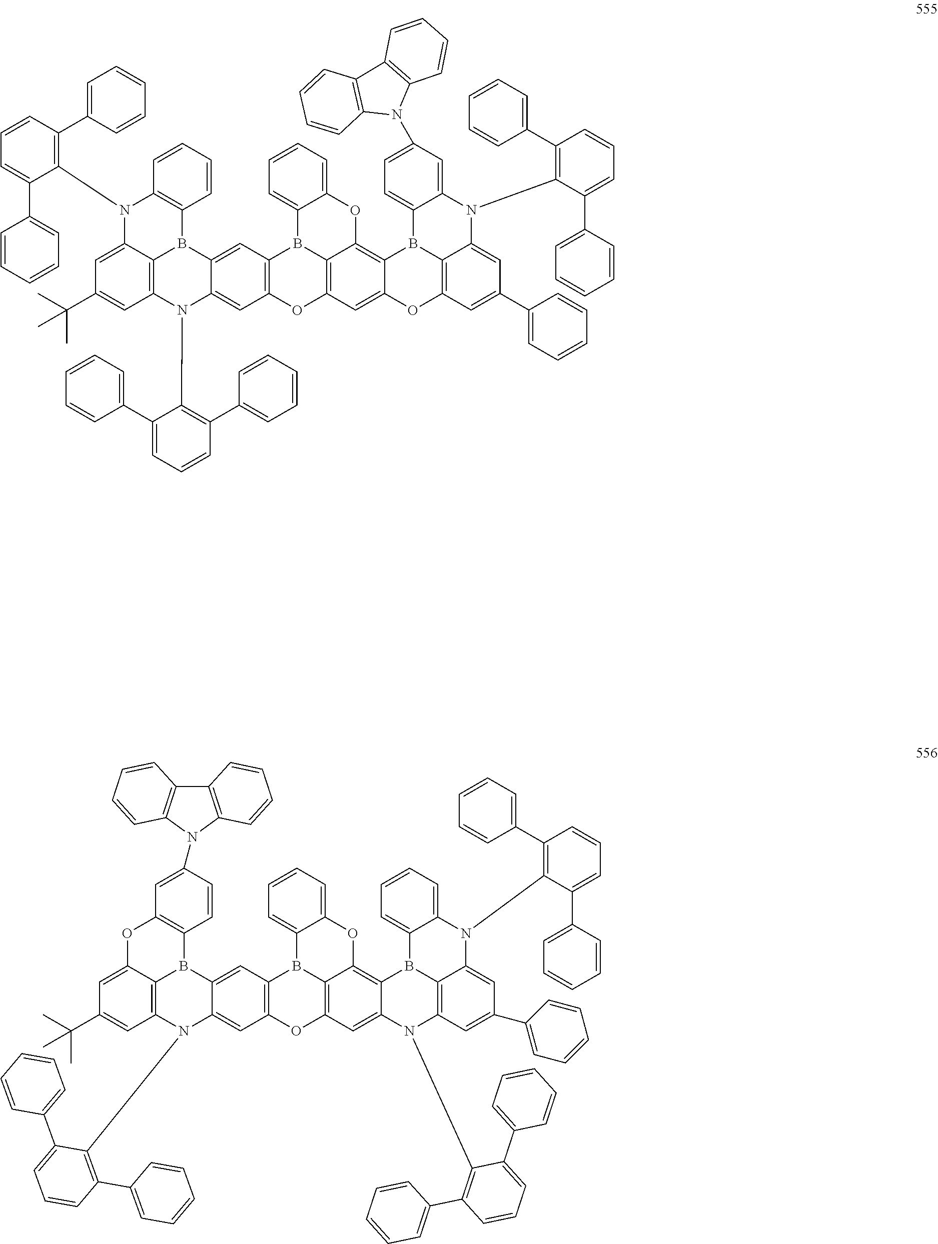 [SMILES: CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2Oc2c1c(cc1c2B2c3ccc(-n5c6ccccc6c6ccccc65)cc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccccc2Oc2c1c(cc1c2B2c3ccccc3N(c3c(-c5ccccc5)cccc3-c3ccccc3)c3cc(-c5ccccc5)cc(c32)N1c1c(-c2ccccc2)cccc1-c1ccccc1)O4] 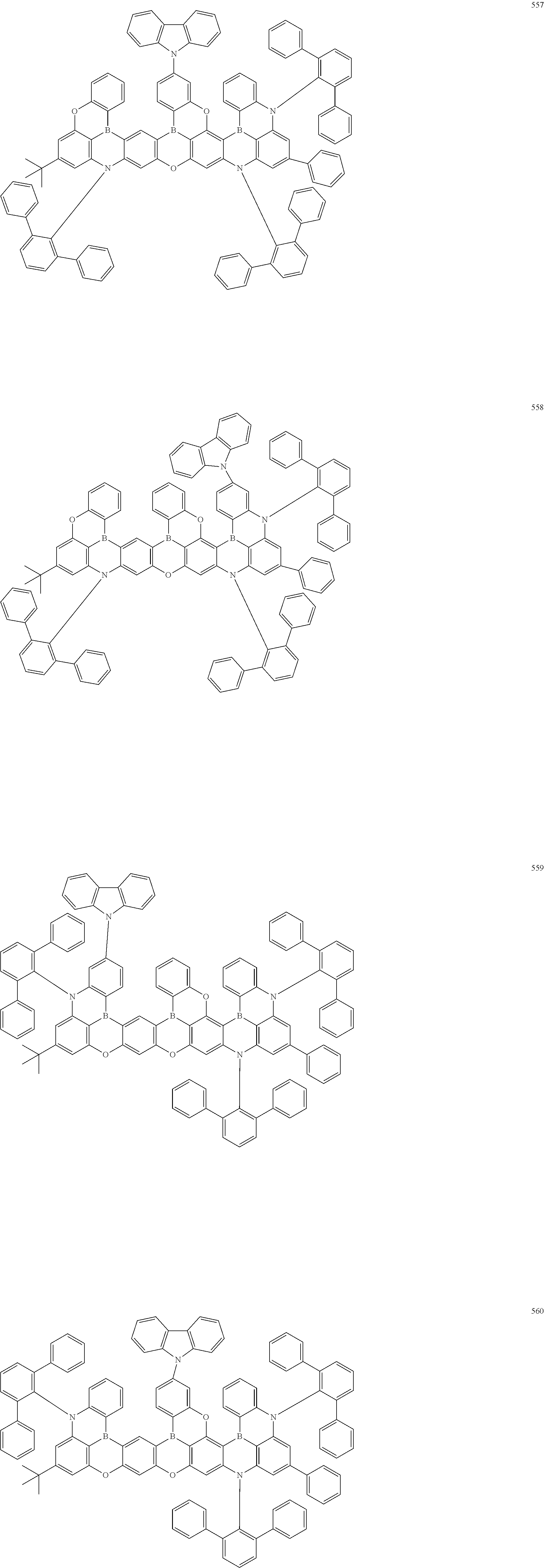 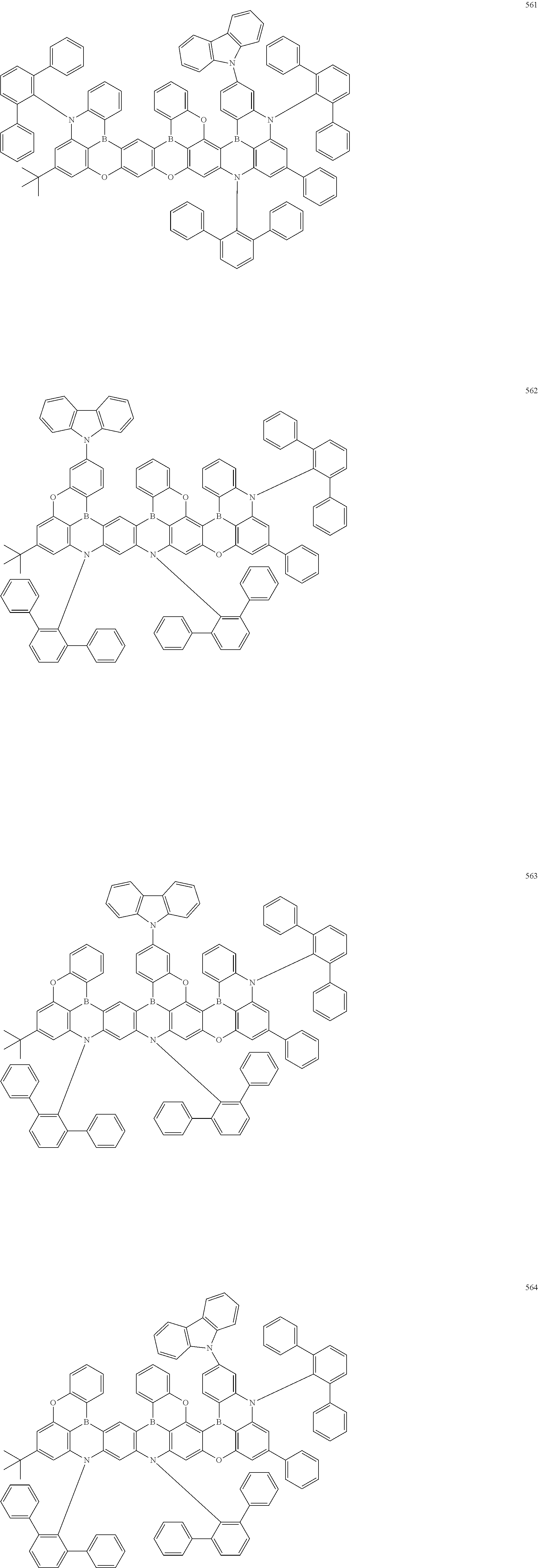 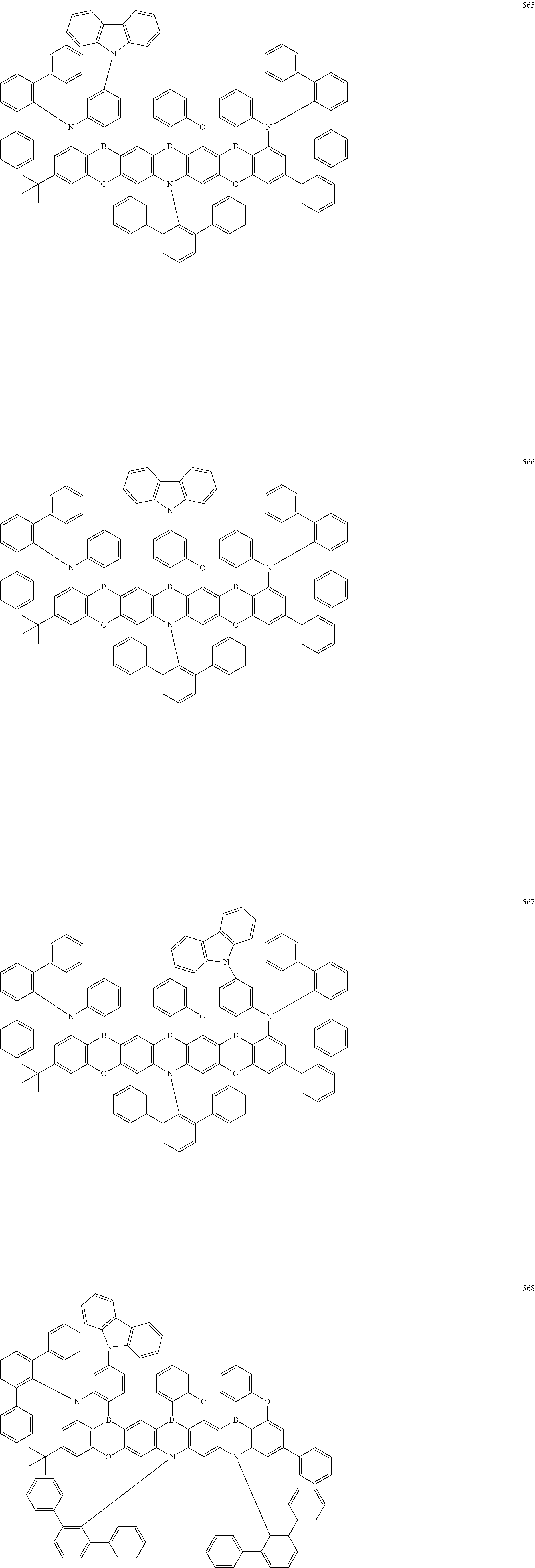 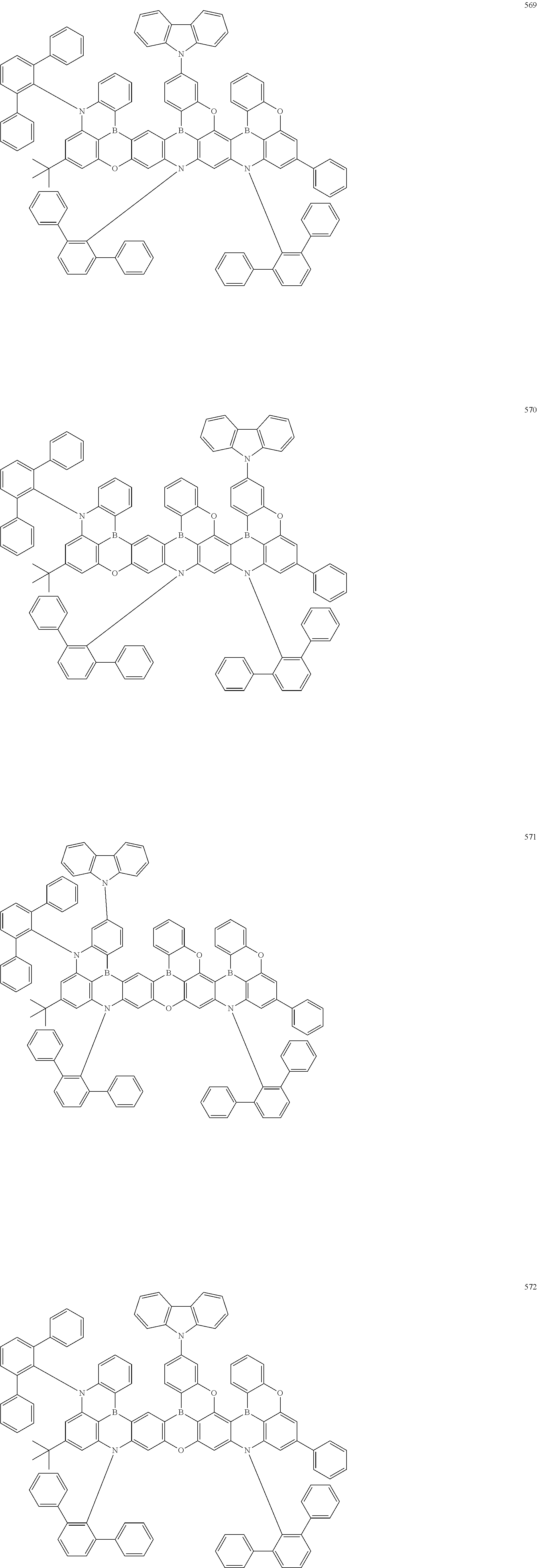 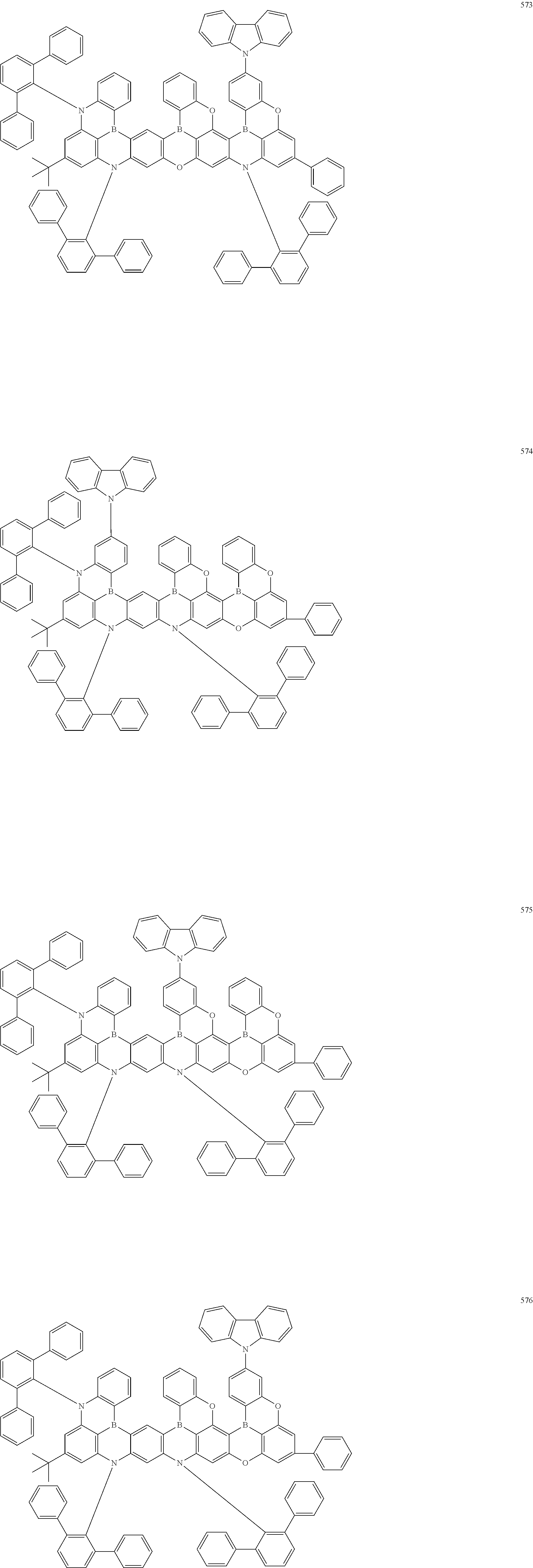 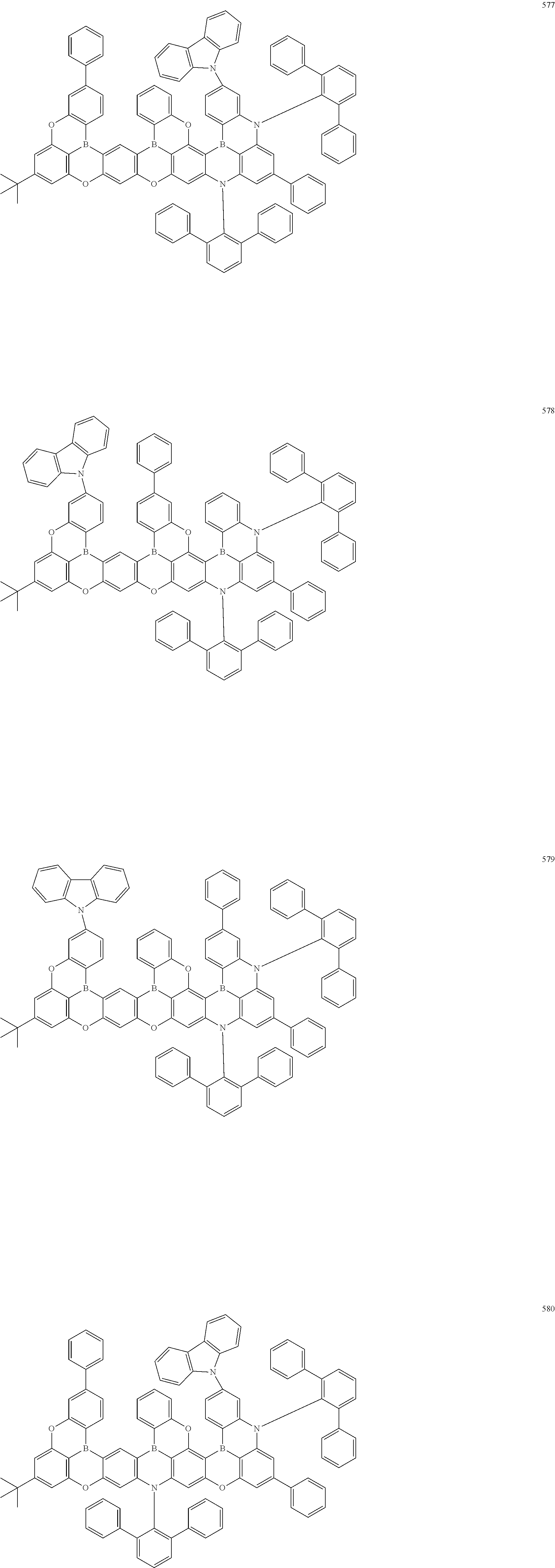 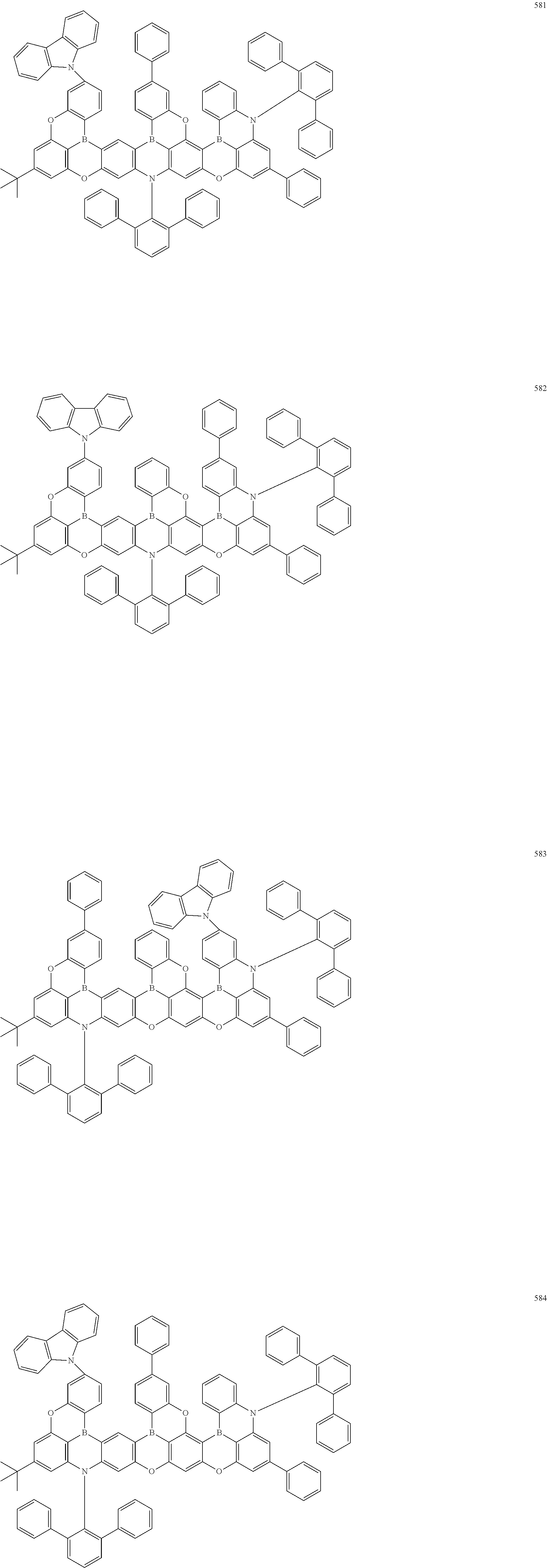 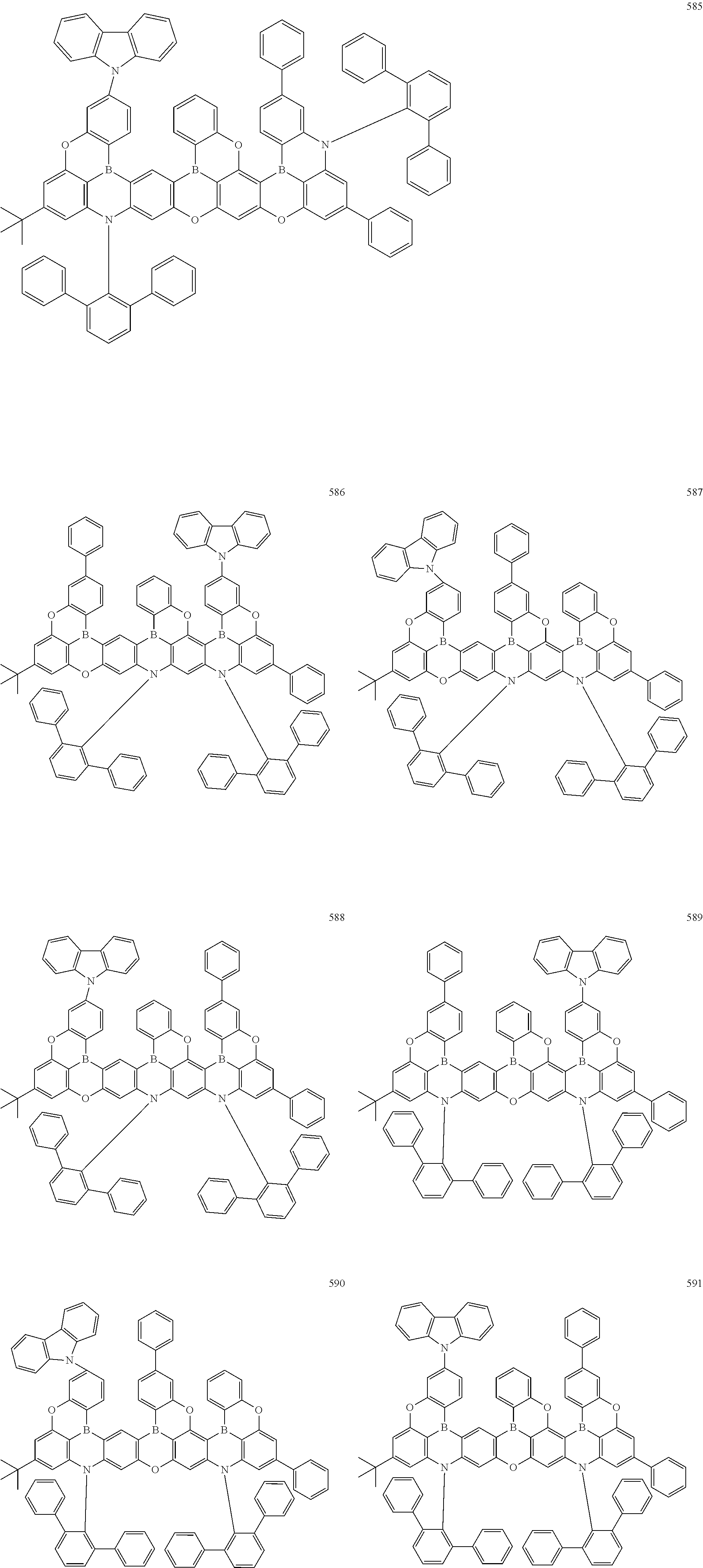 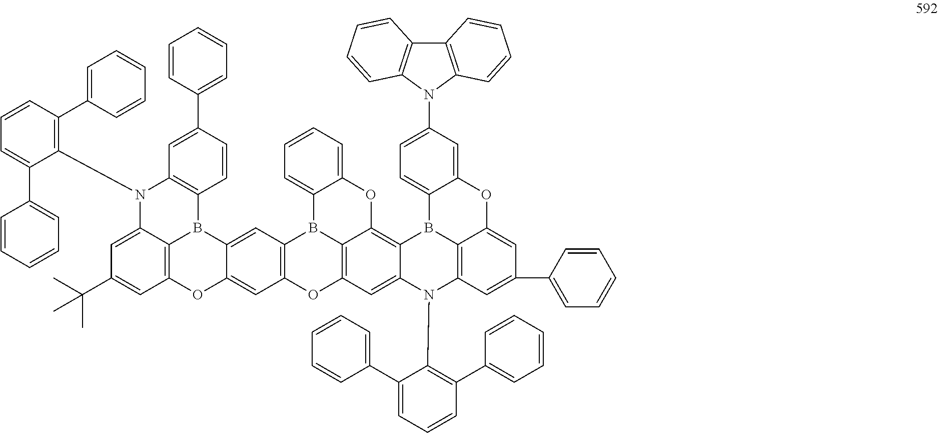 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccccc1O4)B1c3ccc(-n4c5ccccc5c5ccccc54)cc3Oc3cc(-c4ccccc4)cc(c31)N2c1c(-c2ccccc2)cccc1-c1ccccc1] 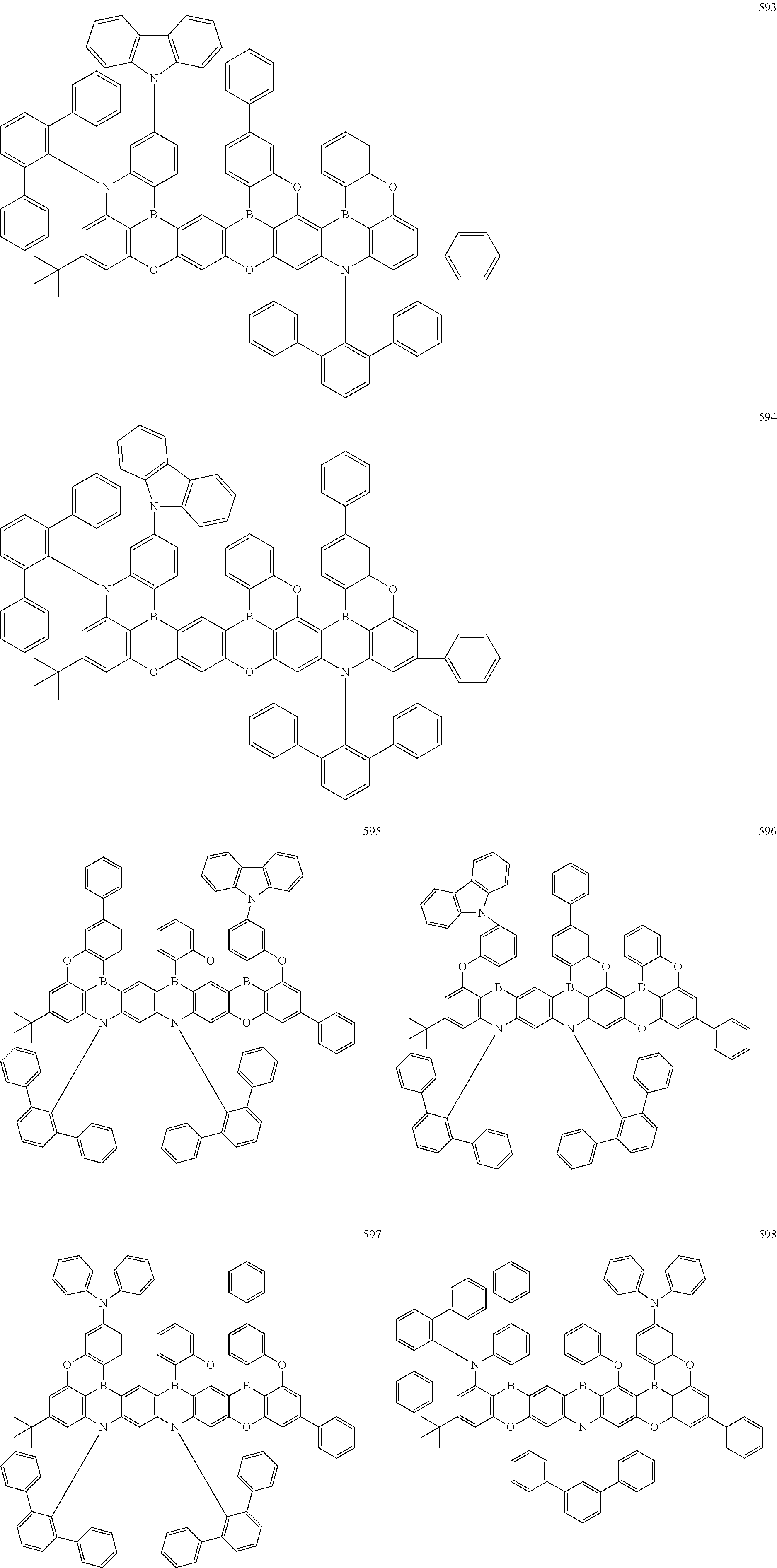 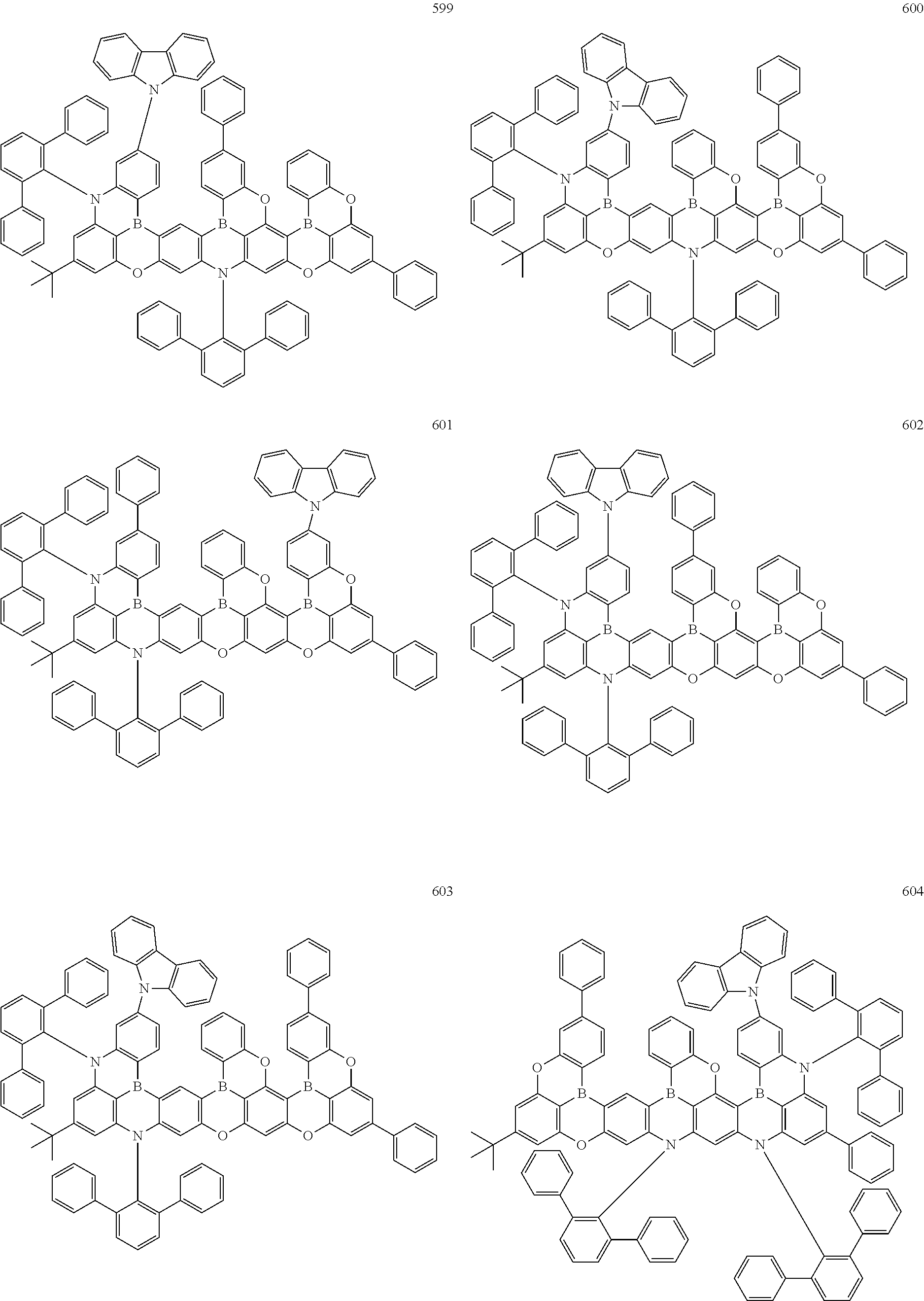 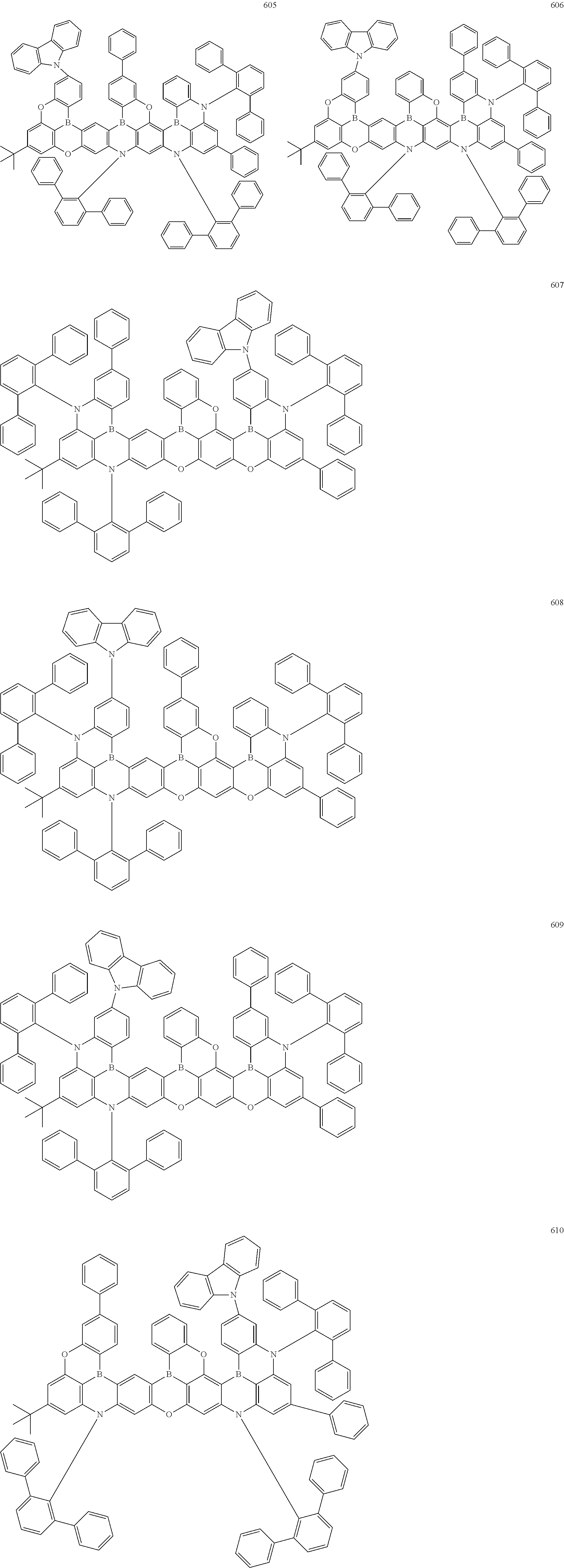 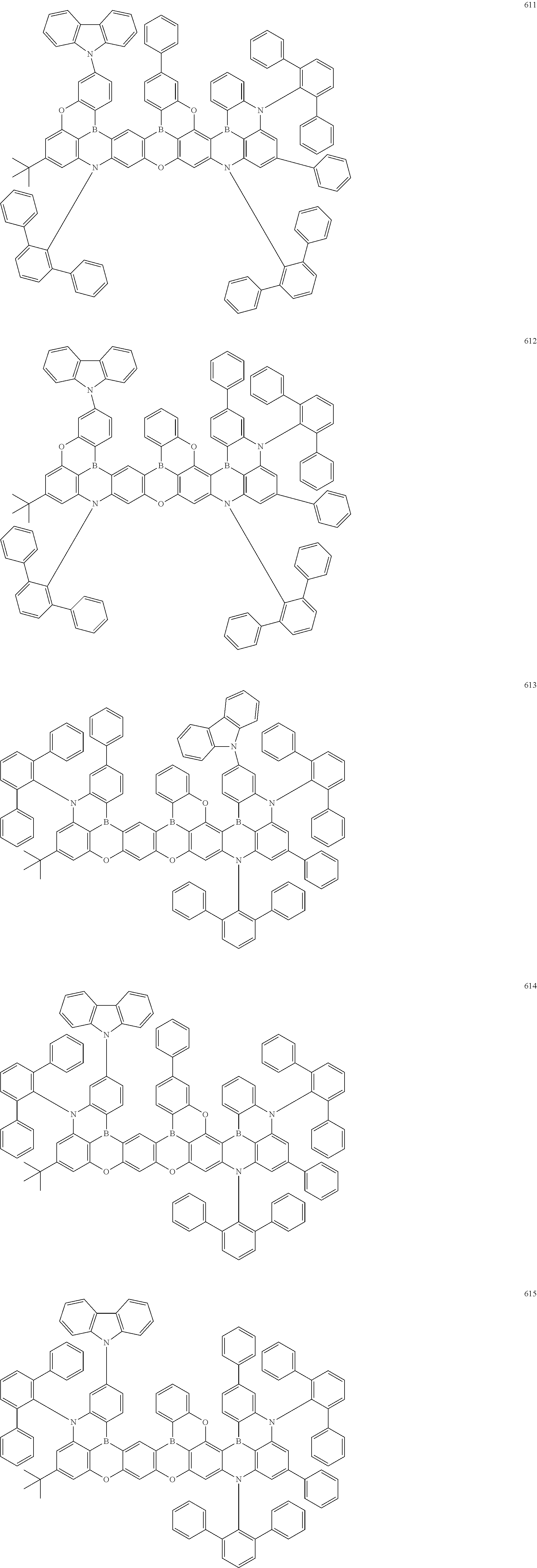 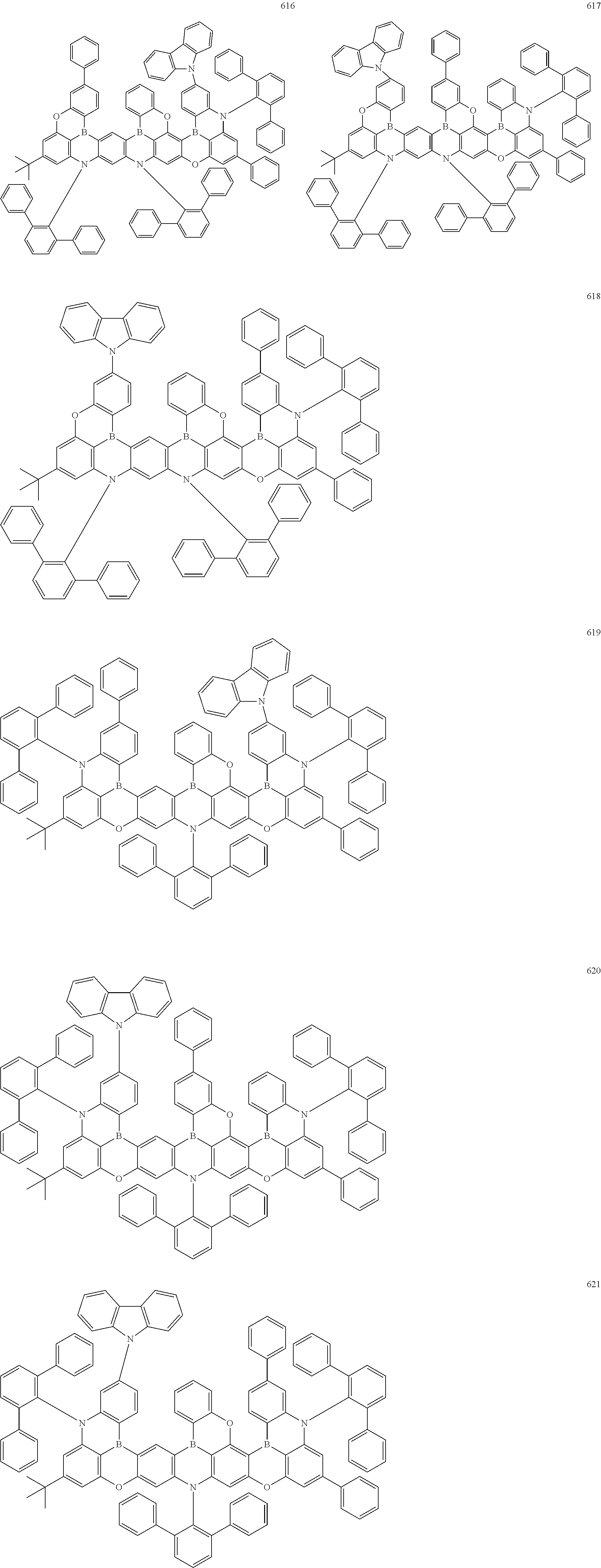 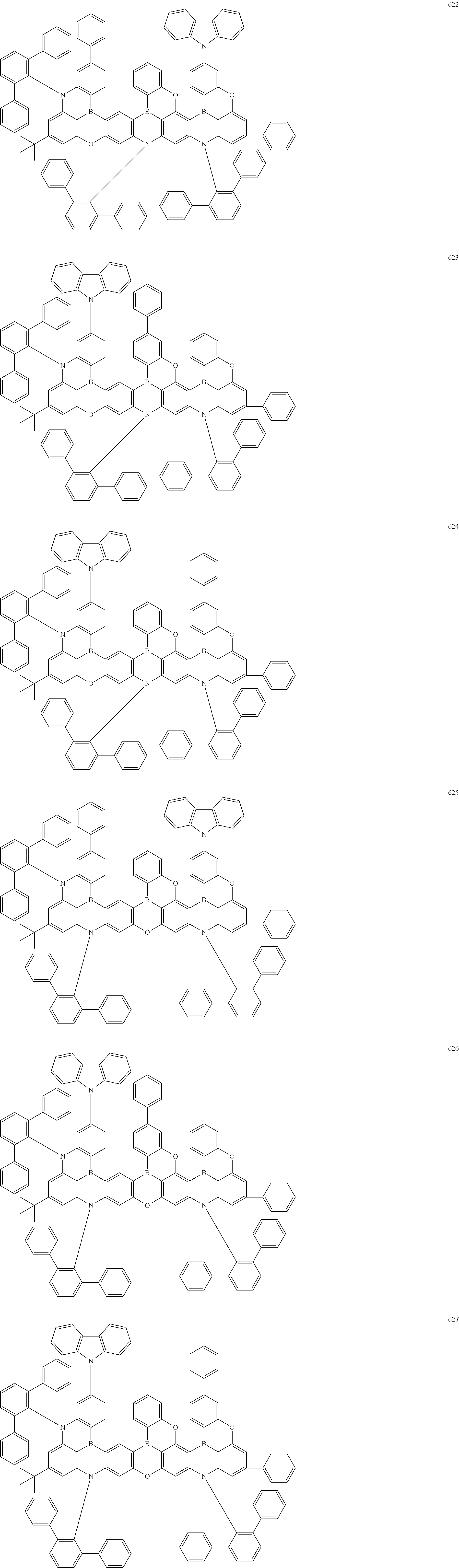 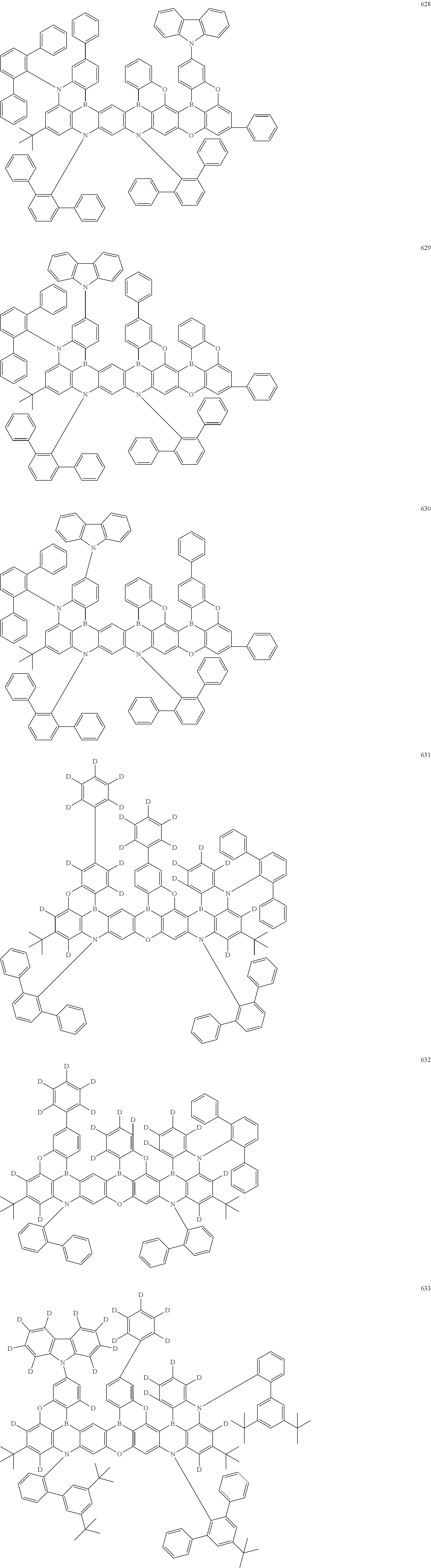 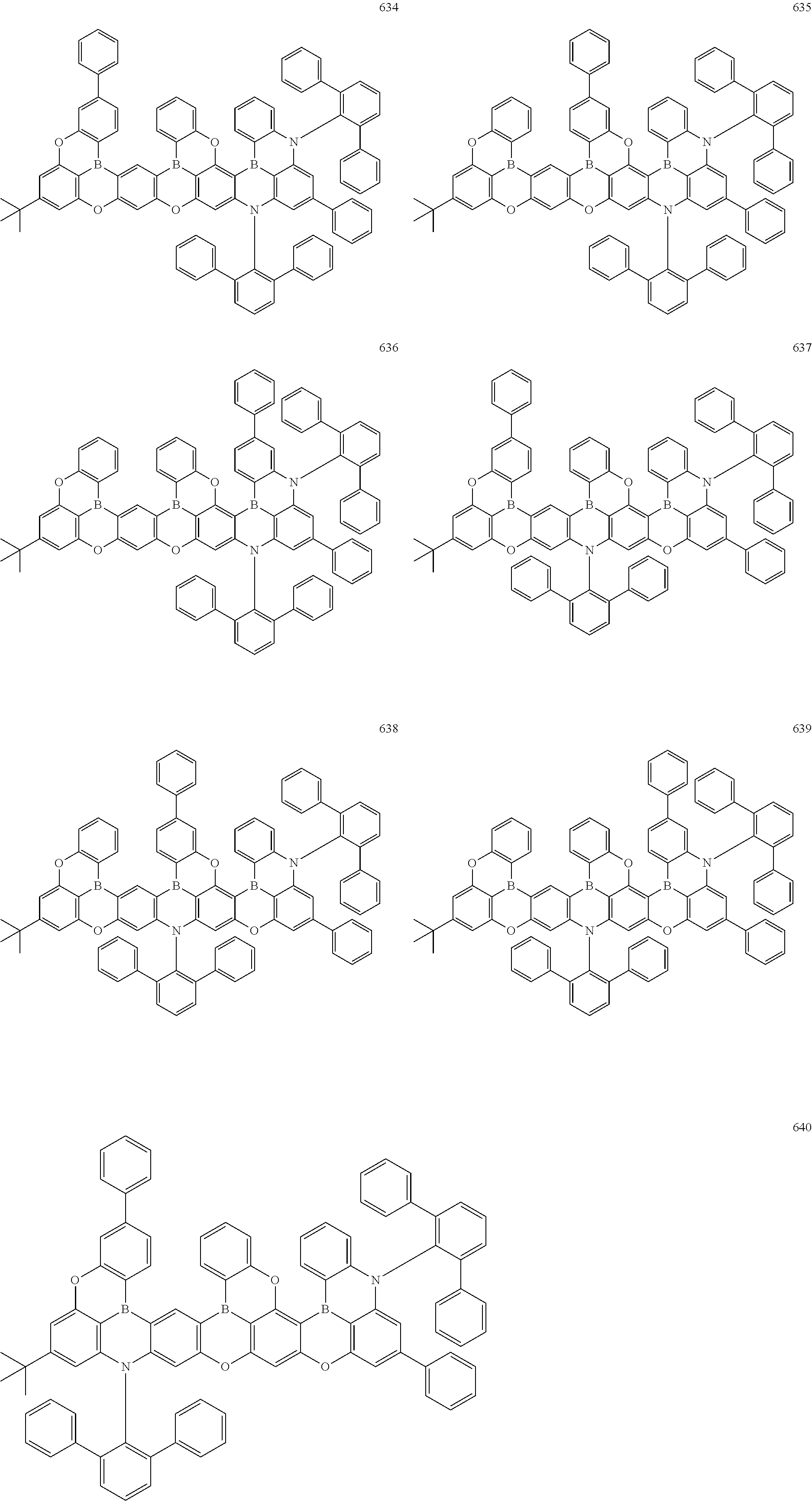 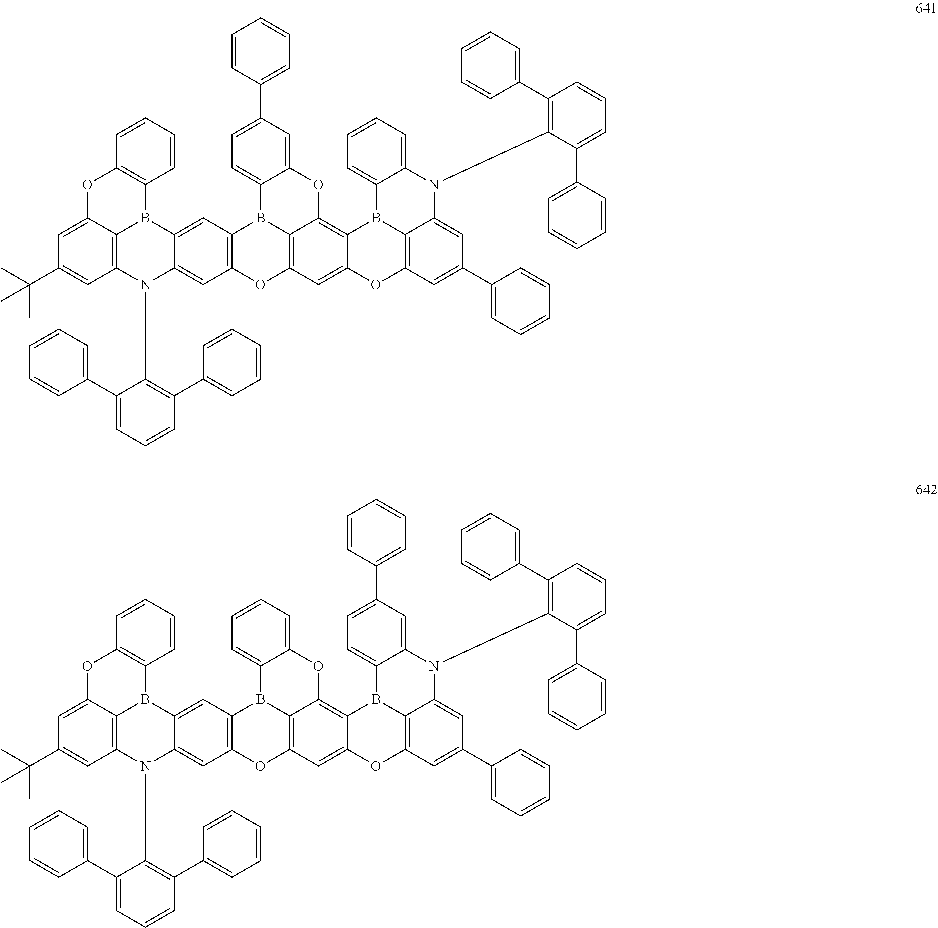 [SMILES: CC(C)(C)c1cc2c3c(c1)N(c1c(-c4ccccc4)cccc1-c1ccccc1)c1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(-c5ccccc5)cc(c32)O1)O4 ; CC(C)(C)c1cc2c3c(c1)N(c1c(-c4ccccc4)cccc1-c1ccccc1)c1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(-c5ccccc5)cc(c32)O1)O4] 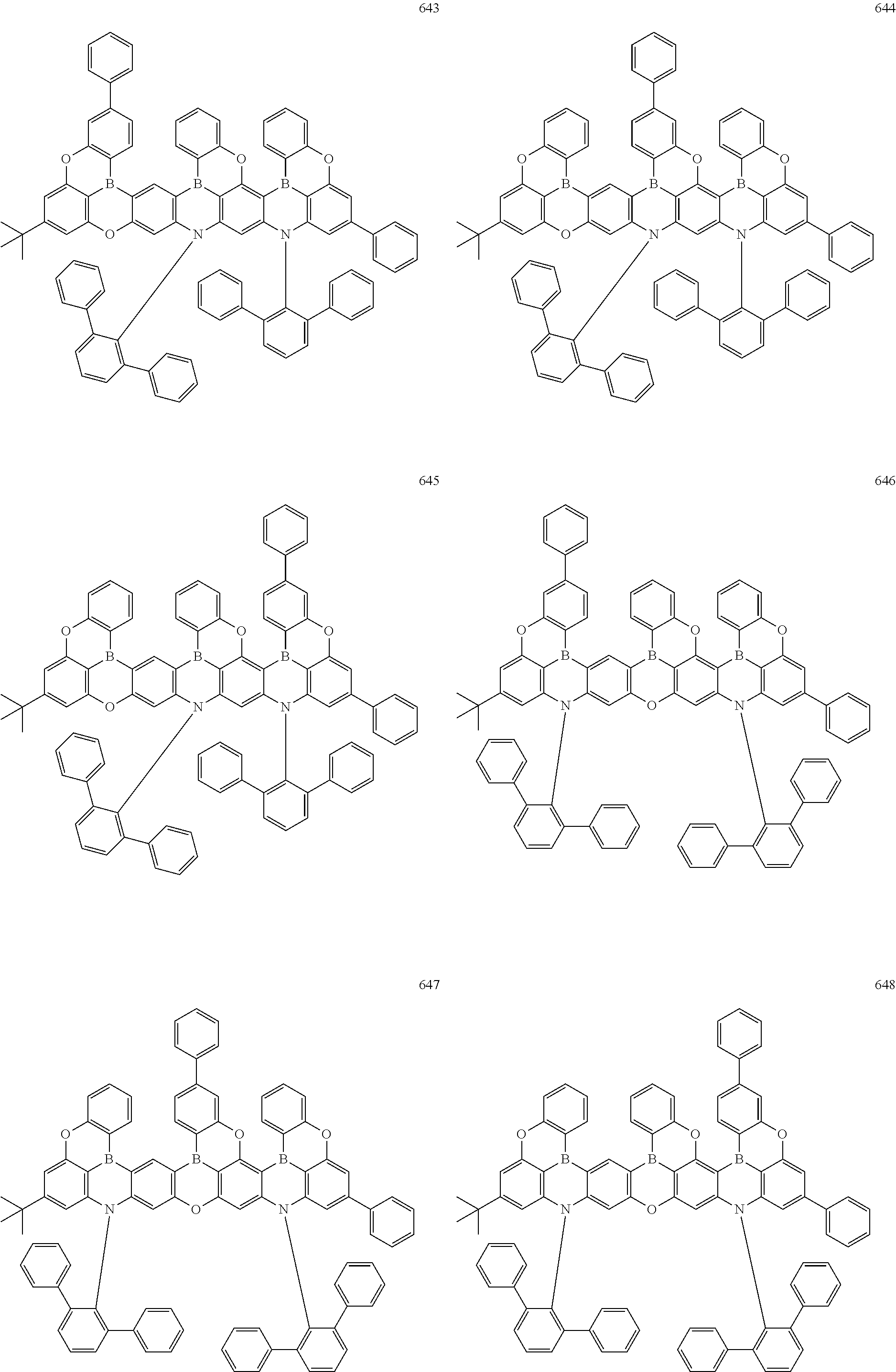 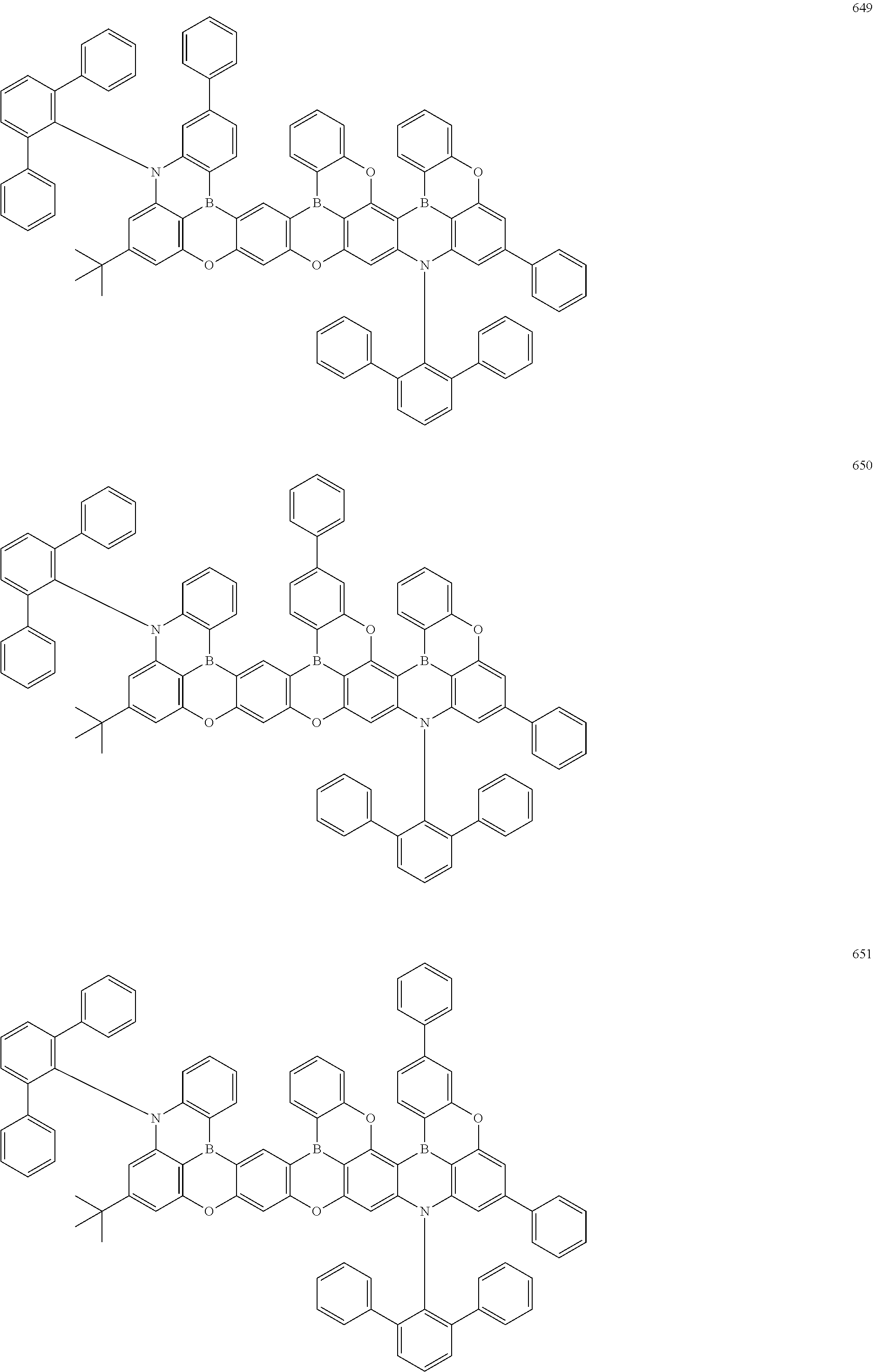 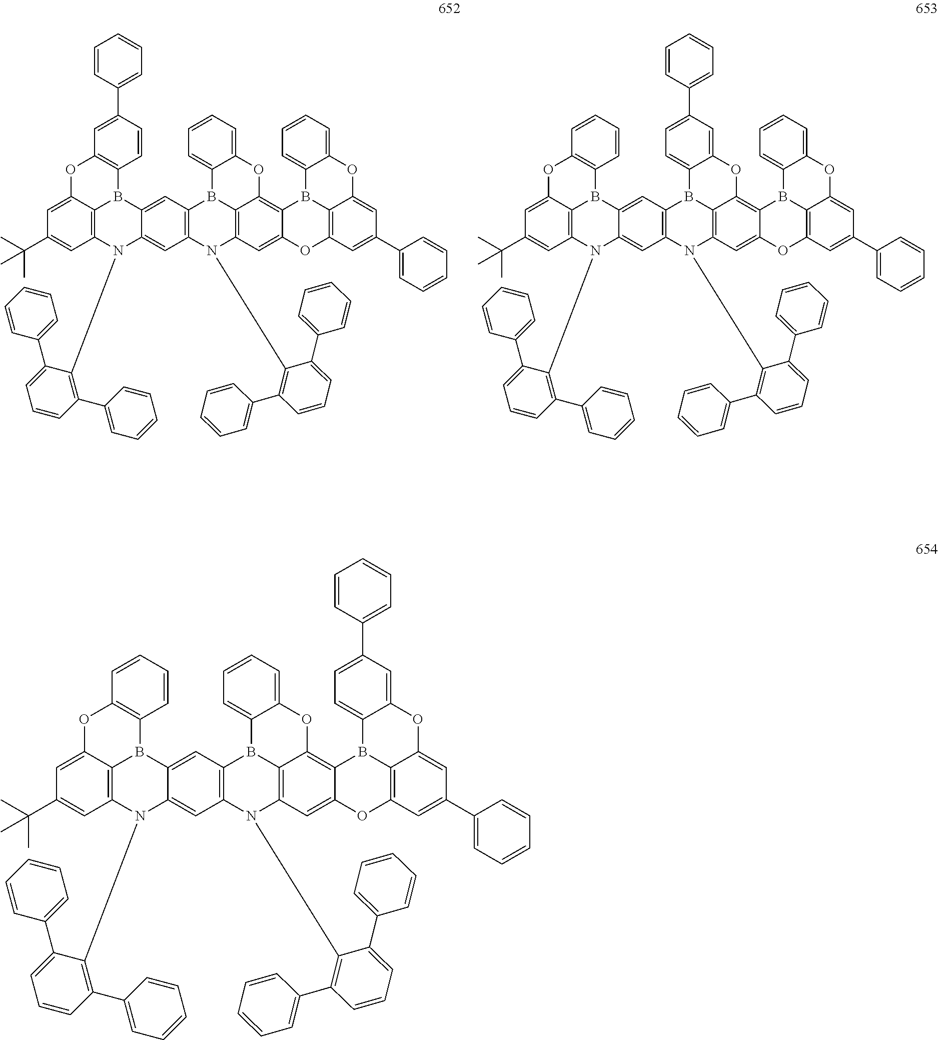 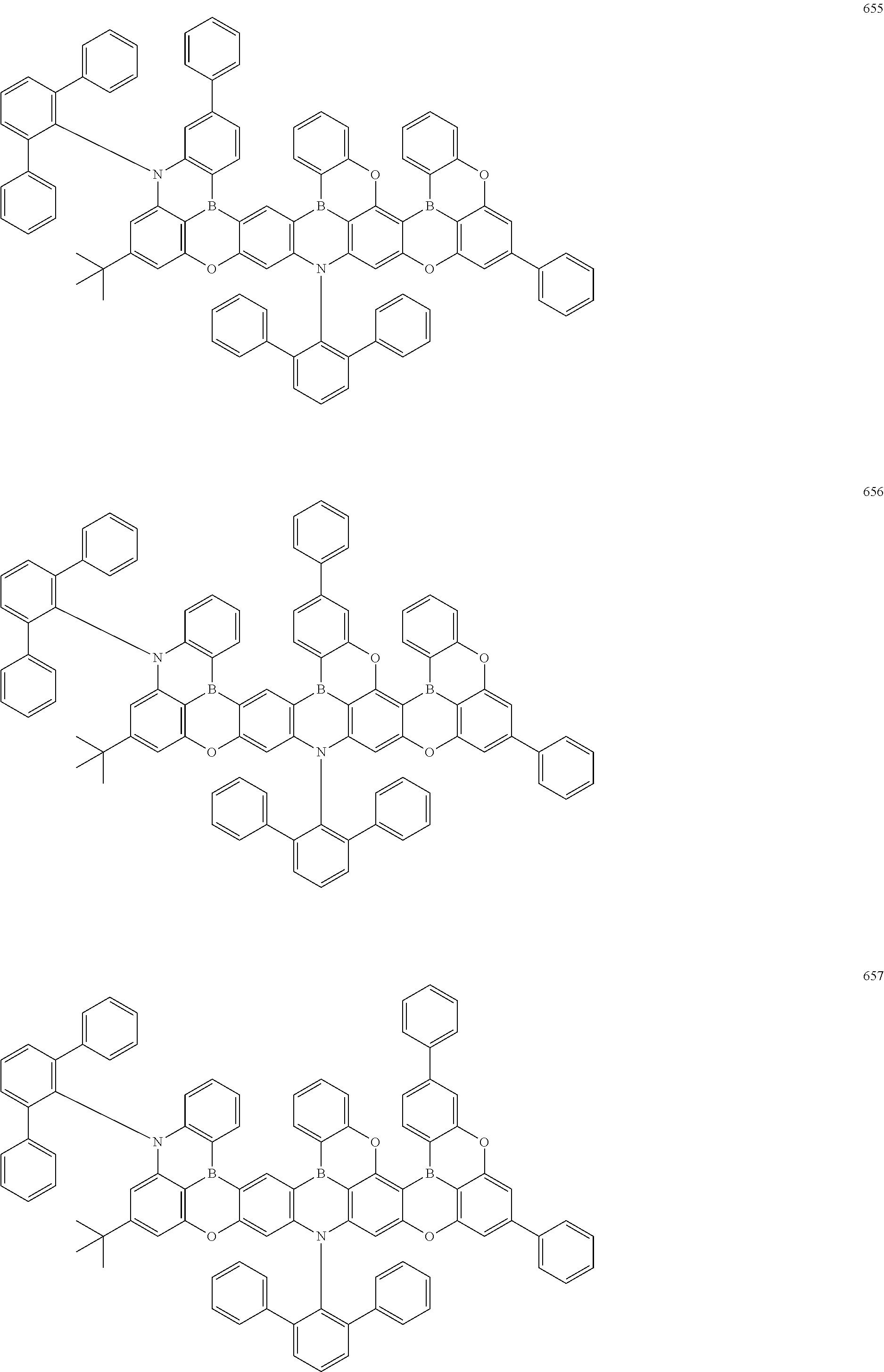 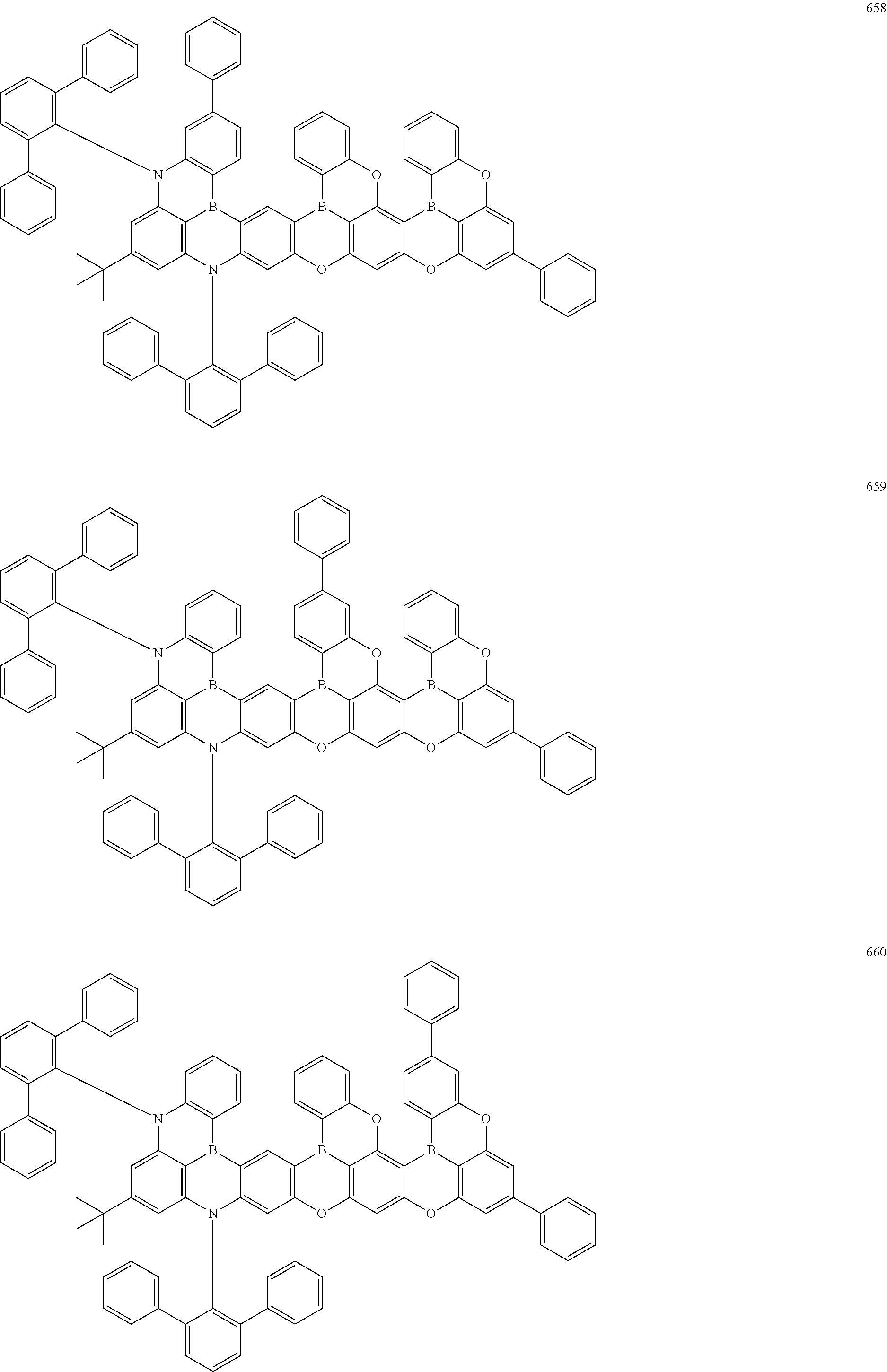 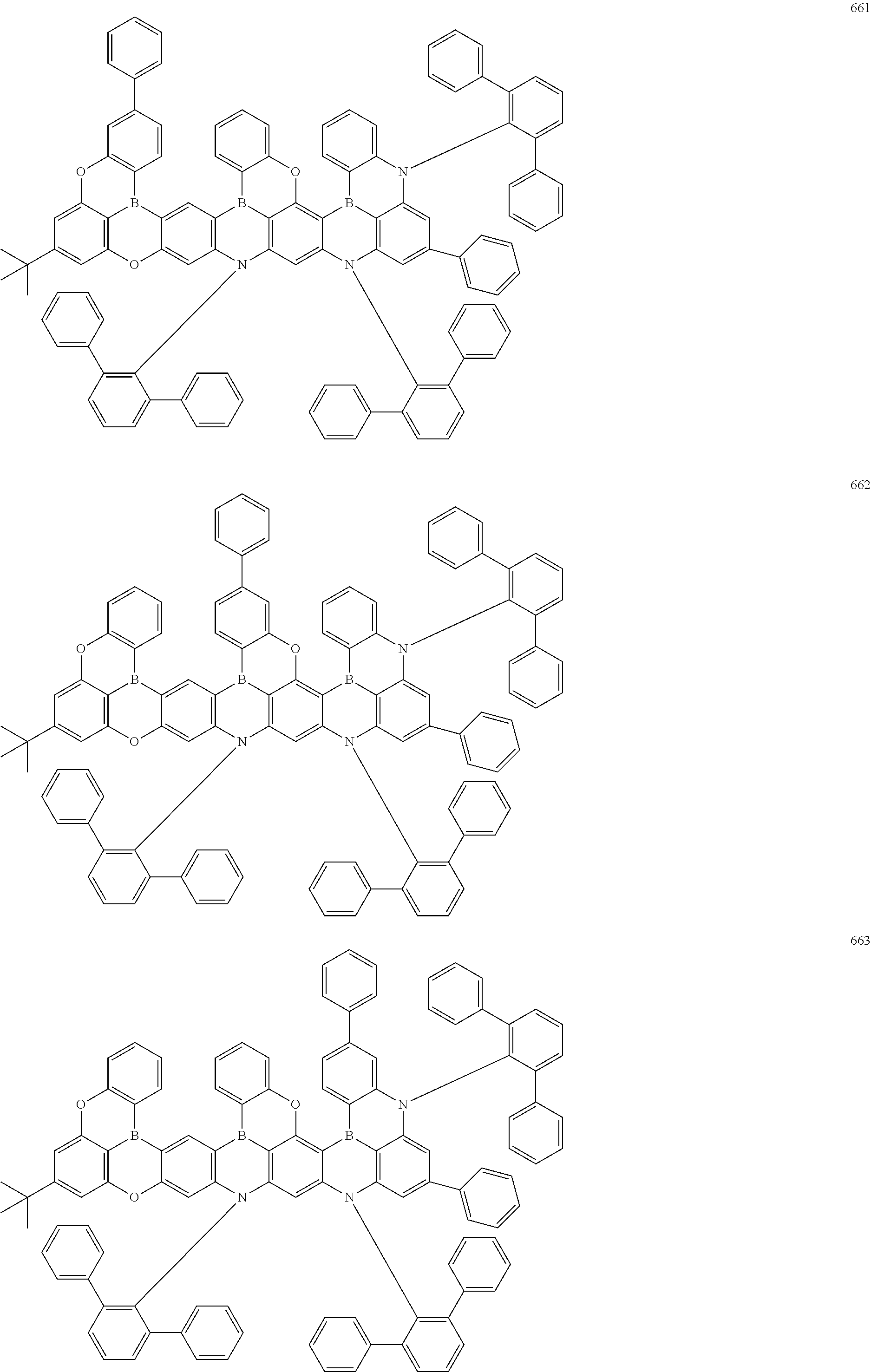 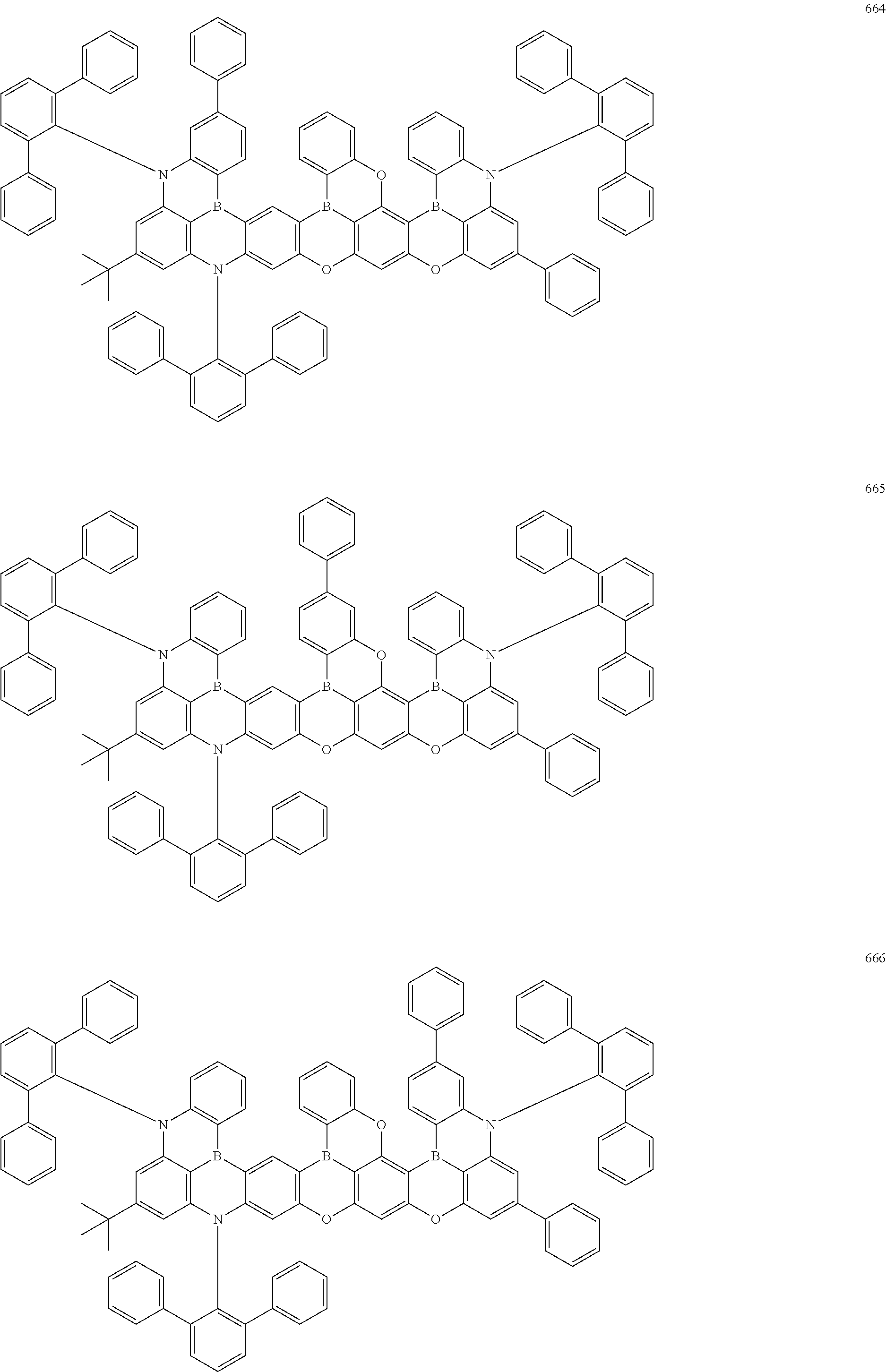 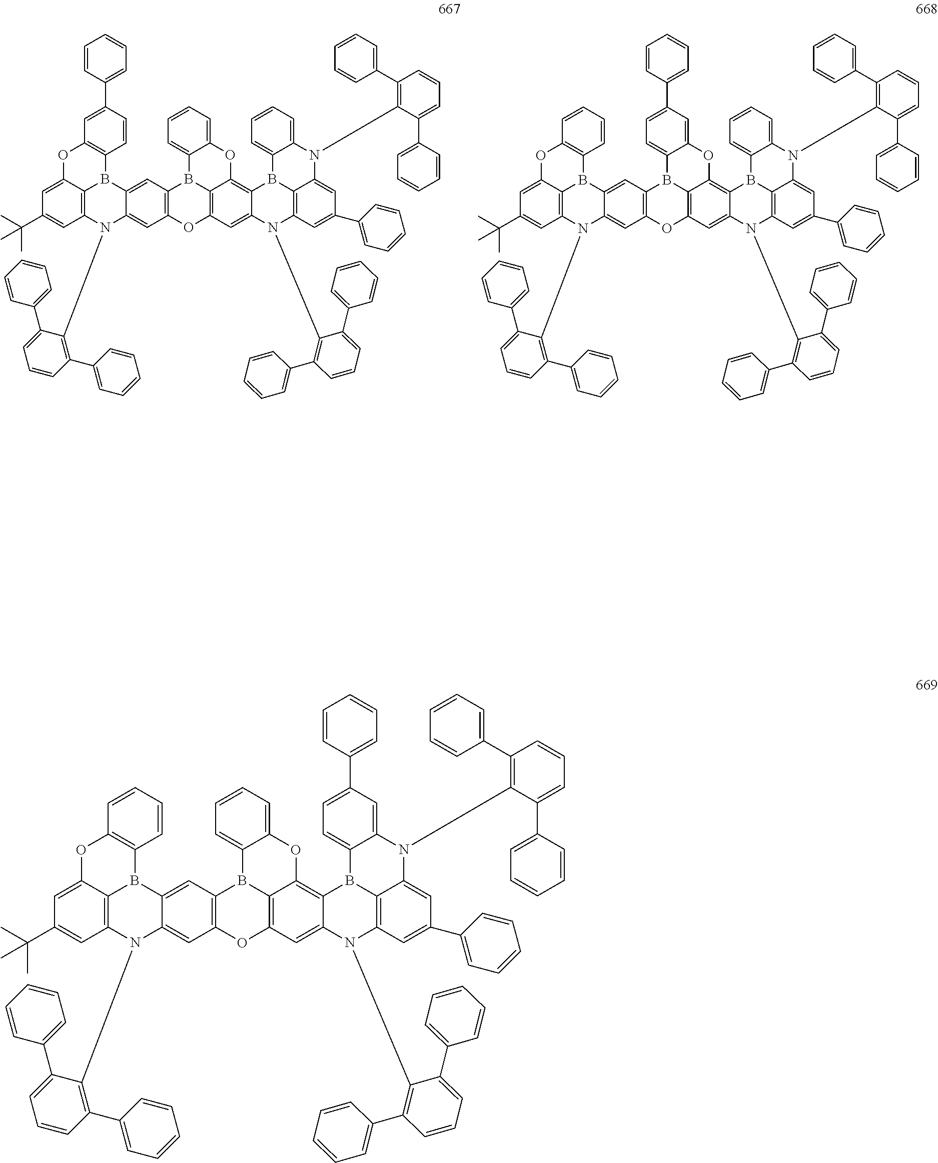 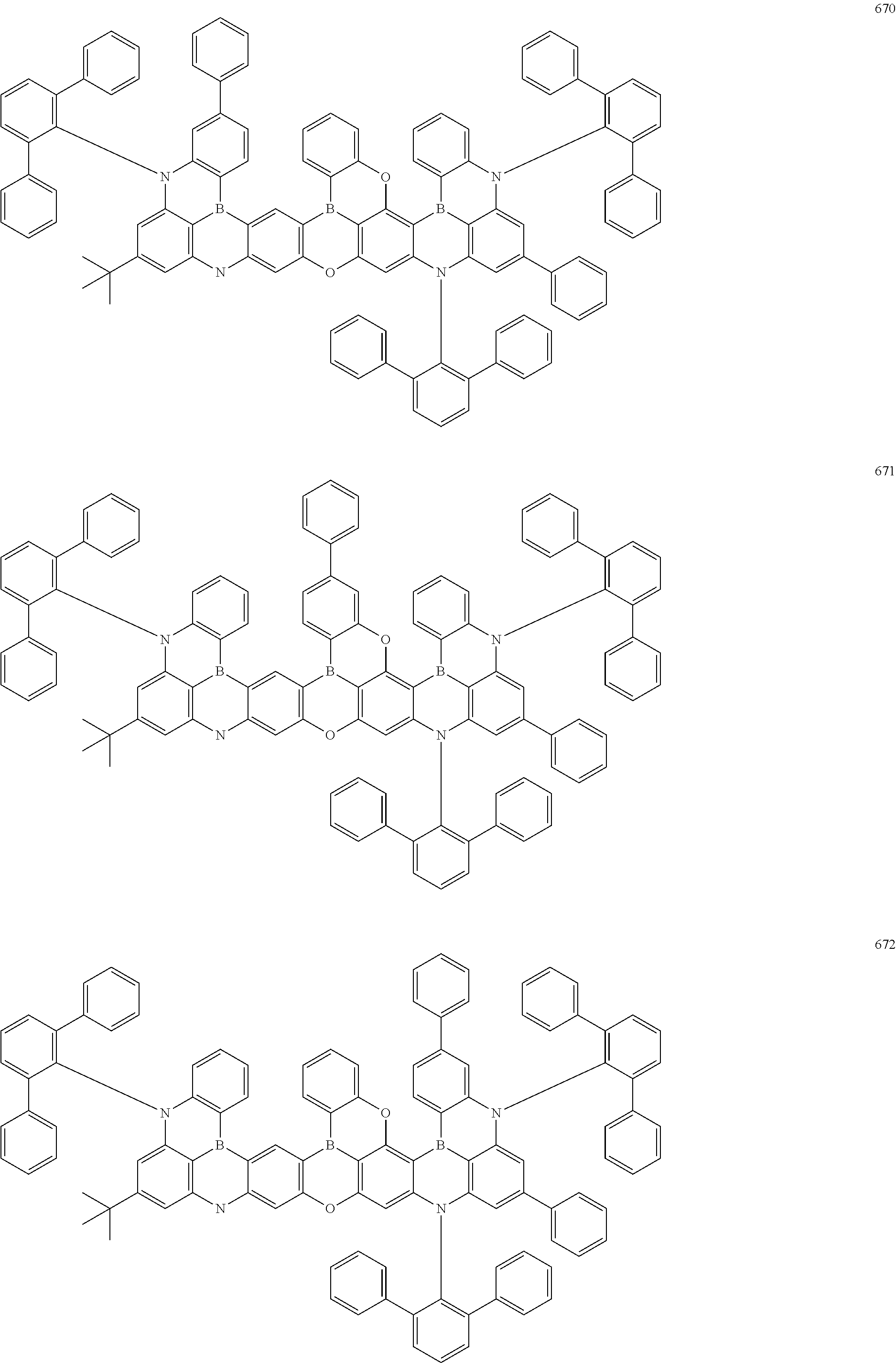 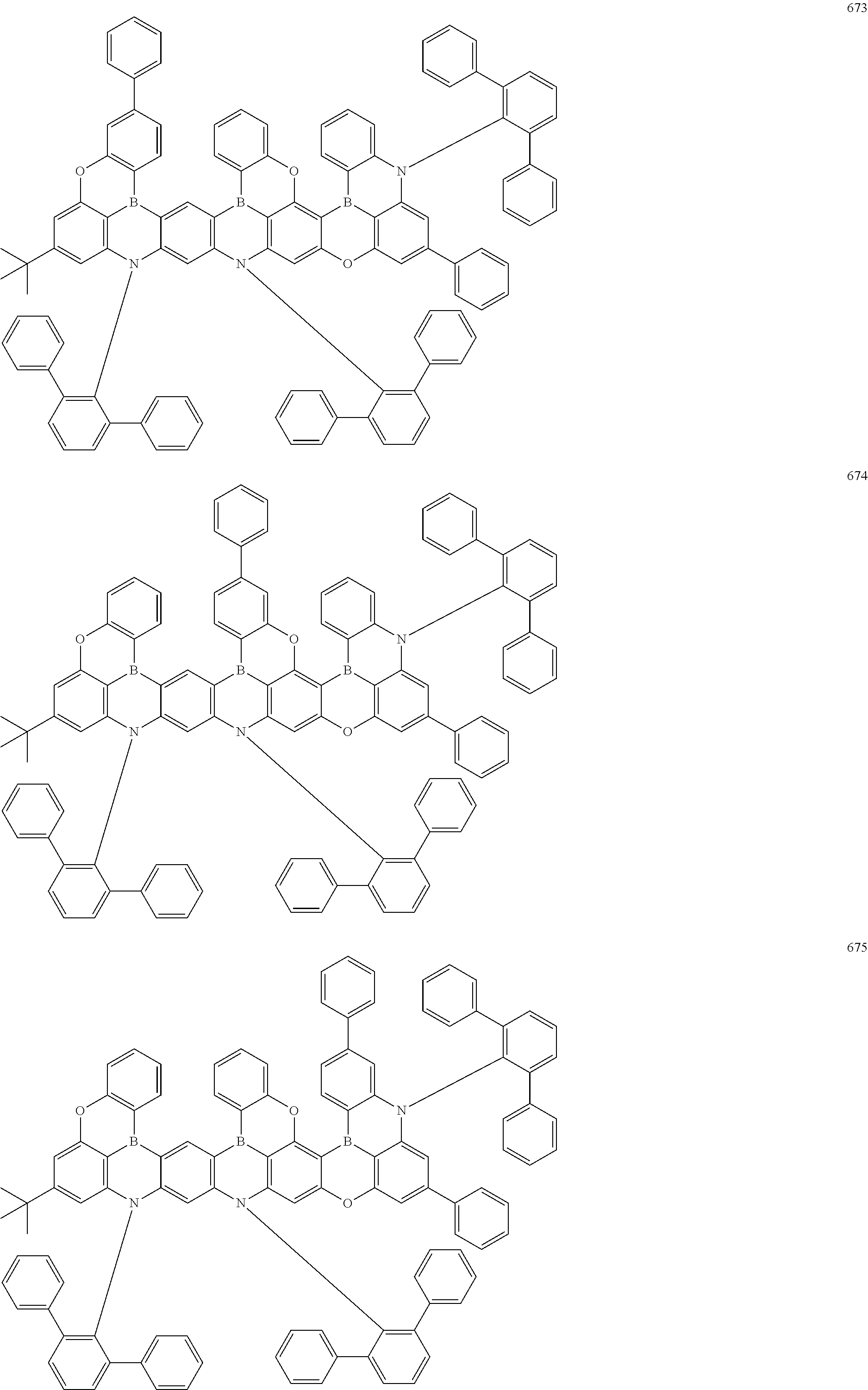 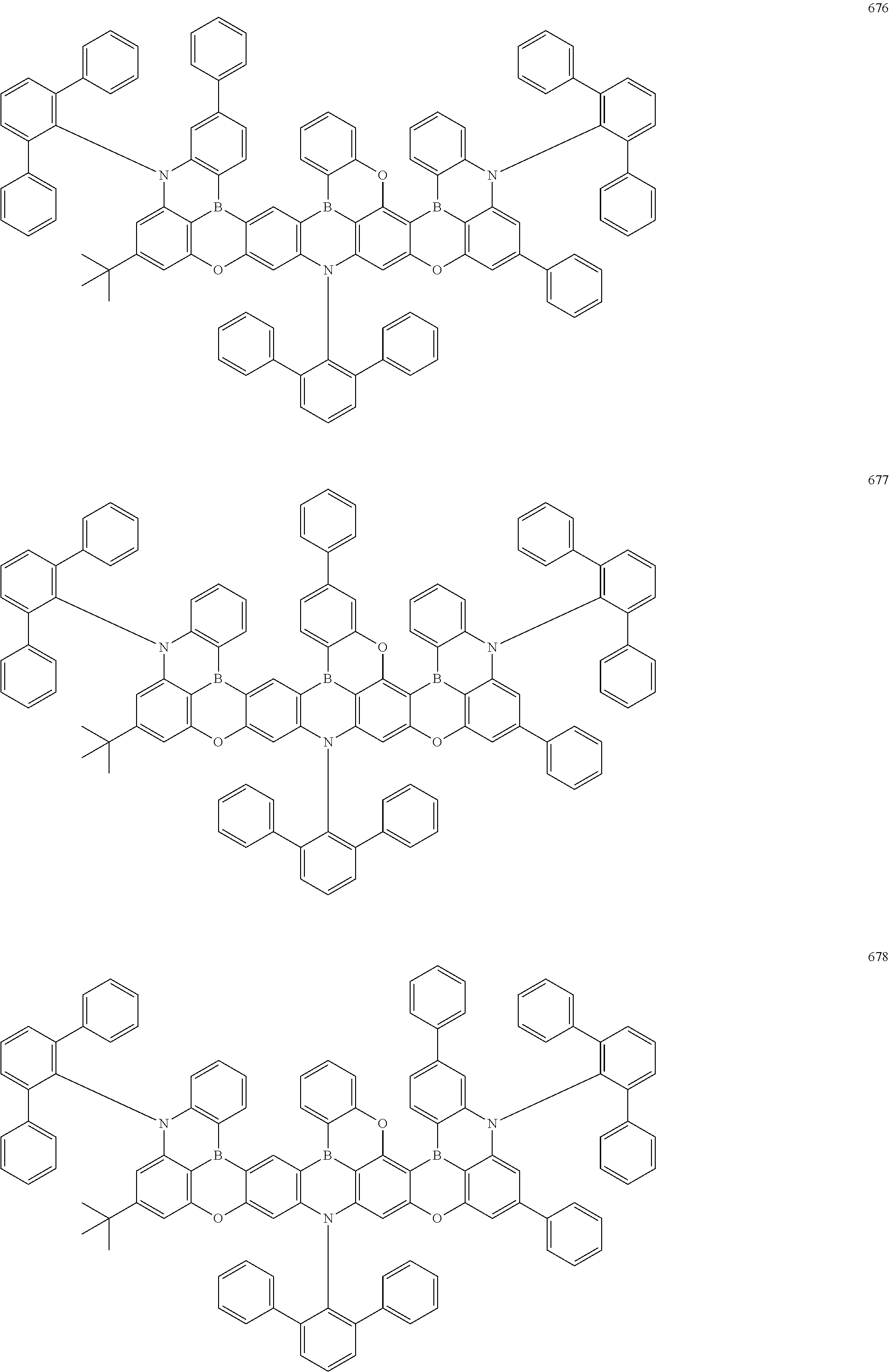 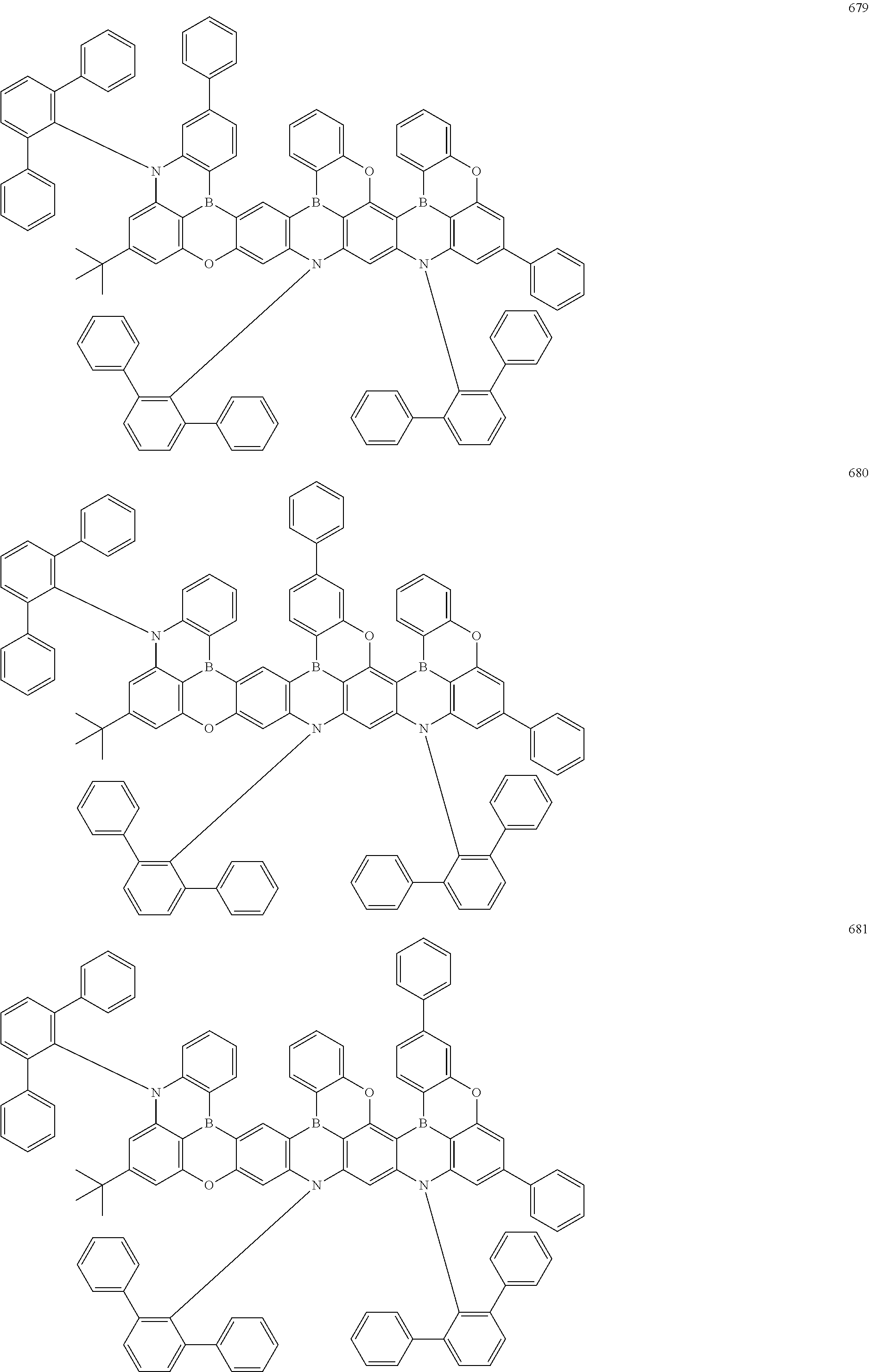 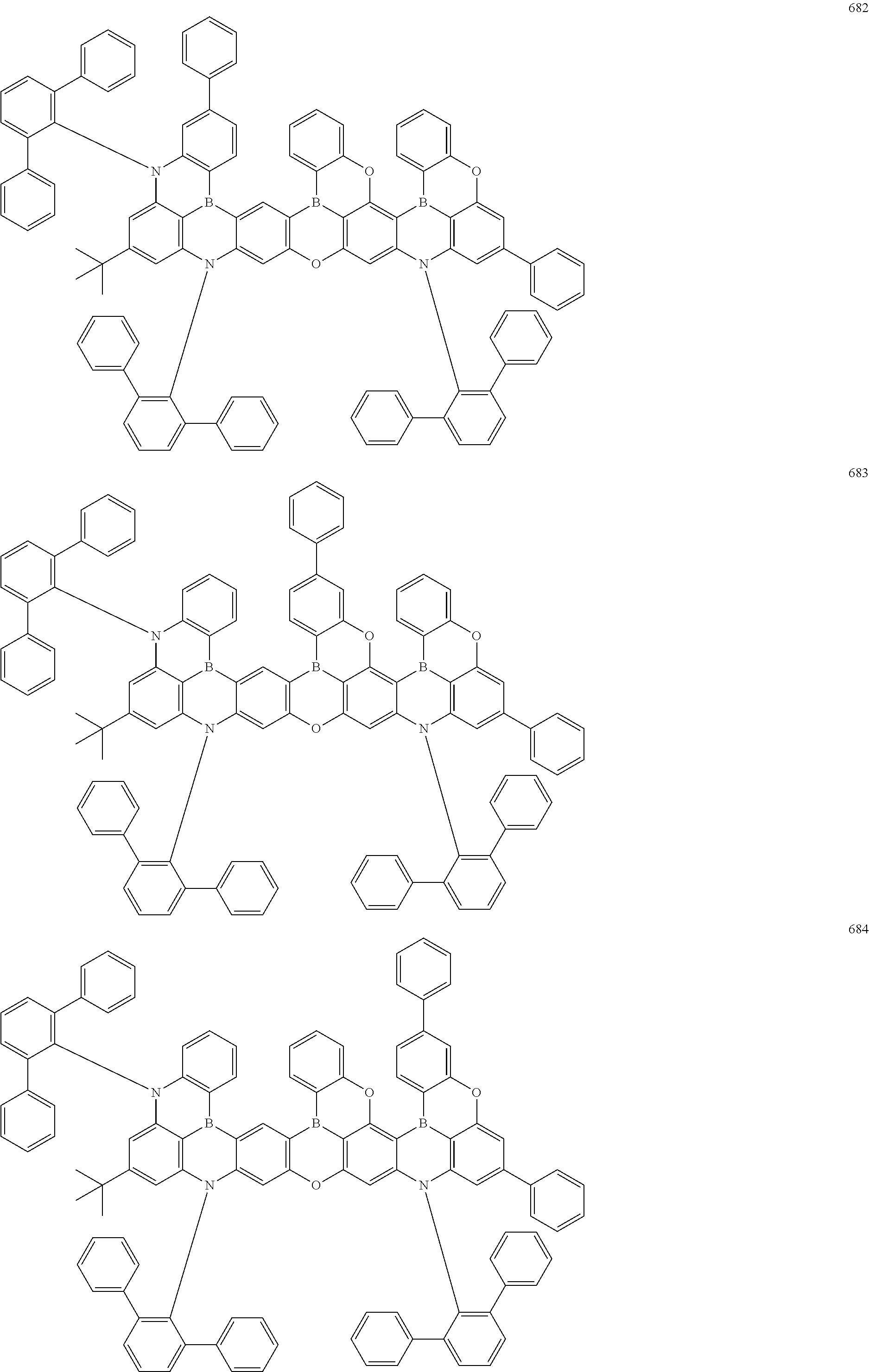 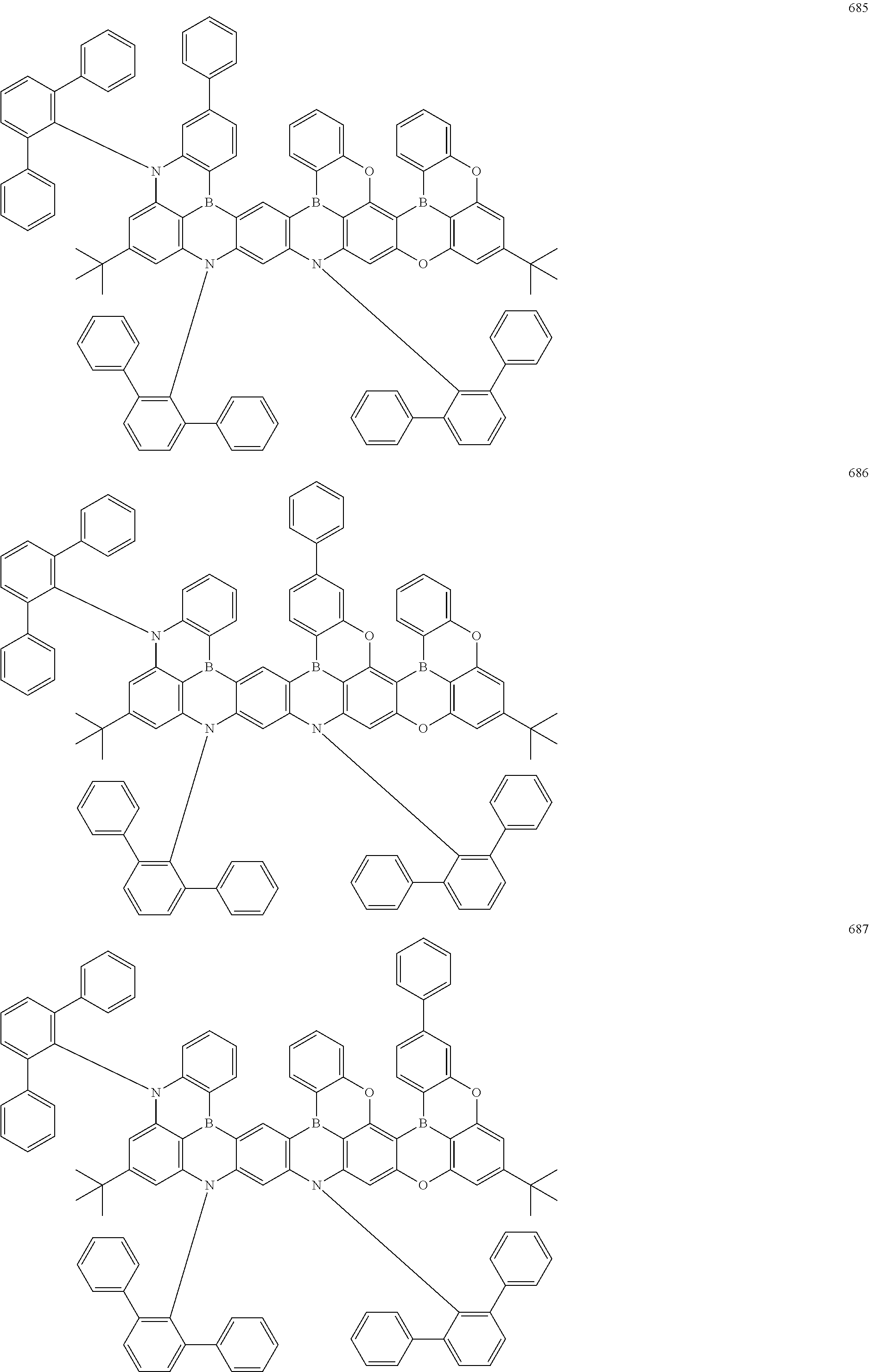 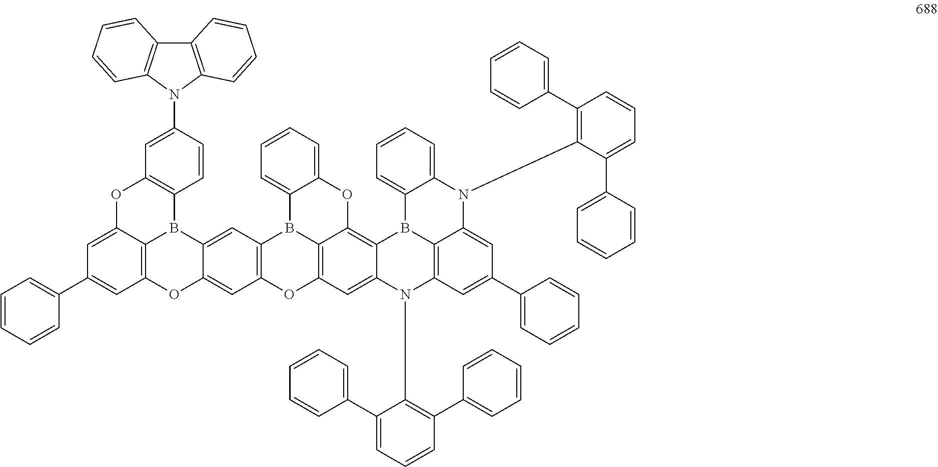 [SMILES: c1ccc(-c2cc3c4c(c2)Oc2cc5c(cc2B4c2ccc(-n4c6ccccc6c6ccccc64)cc2O3)B2c3ccccc3Oc3c2c(cc2c3B3c4ccccc4N(c4c(-c6ccccc6)cccc4-c4ccccc4)c4cc(-c6ccccc6)cc(c43)N2c2c(-c3ccccc3)cccc2-c2ccccc2)O5)cc1] 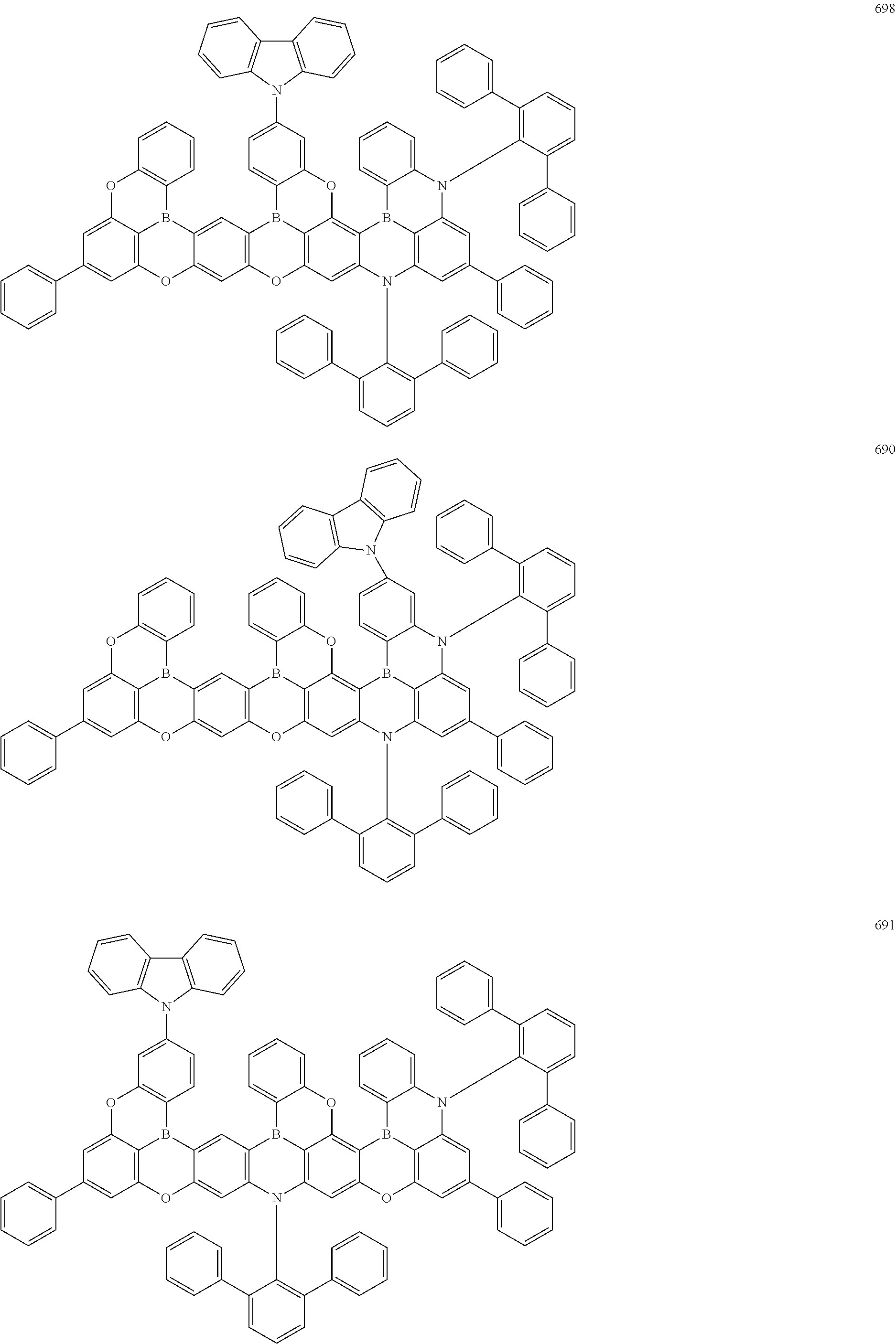 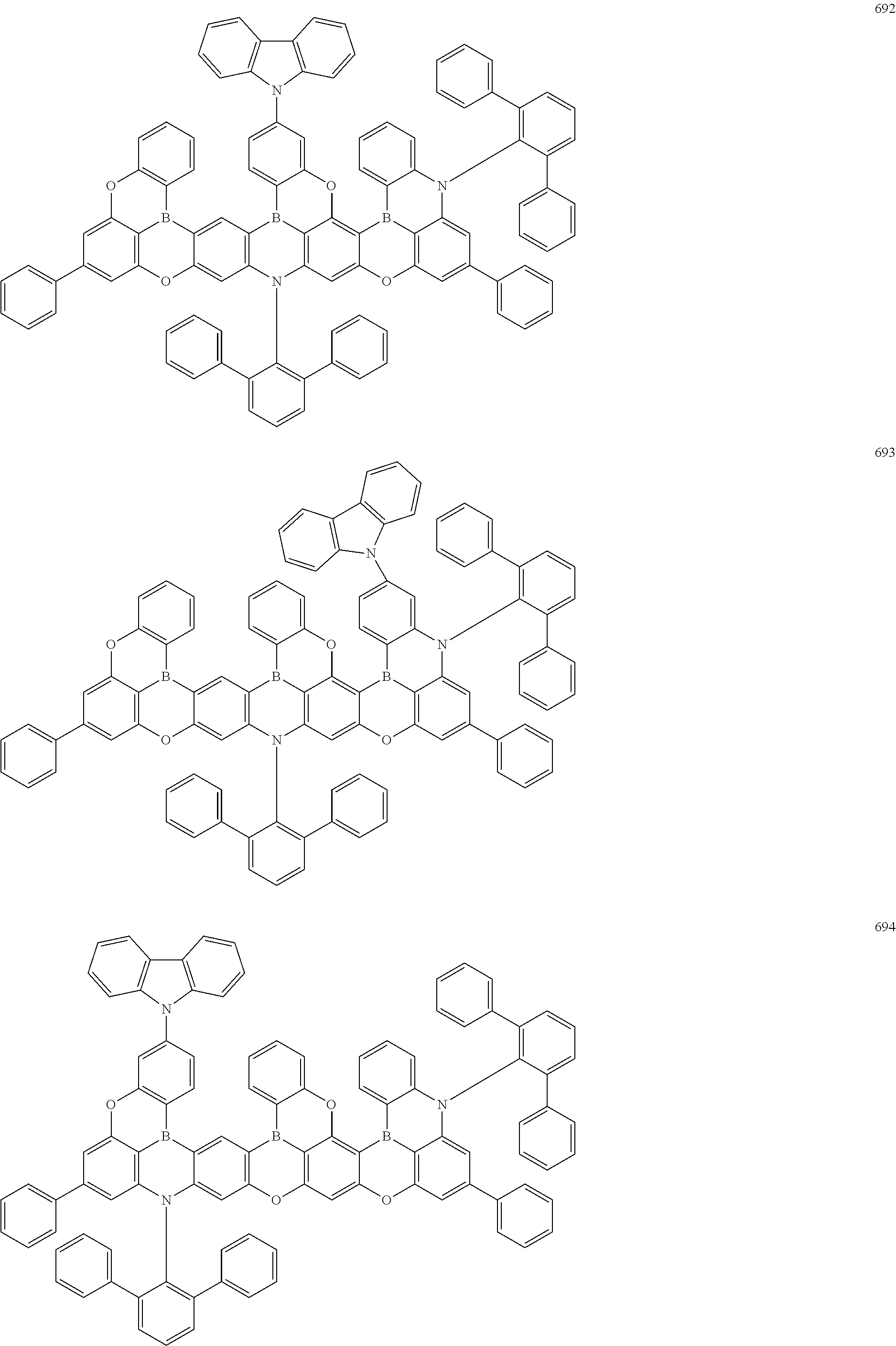 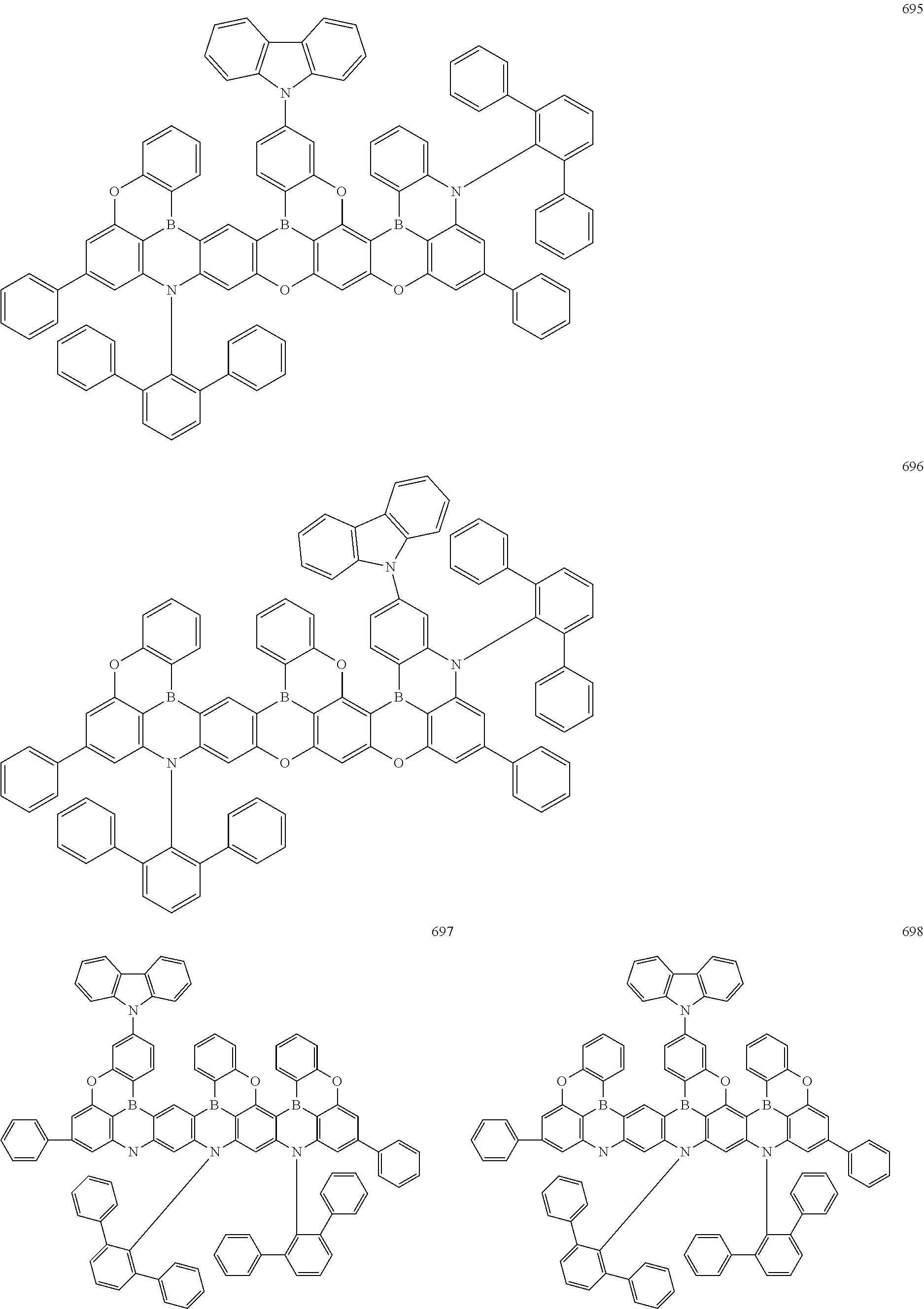 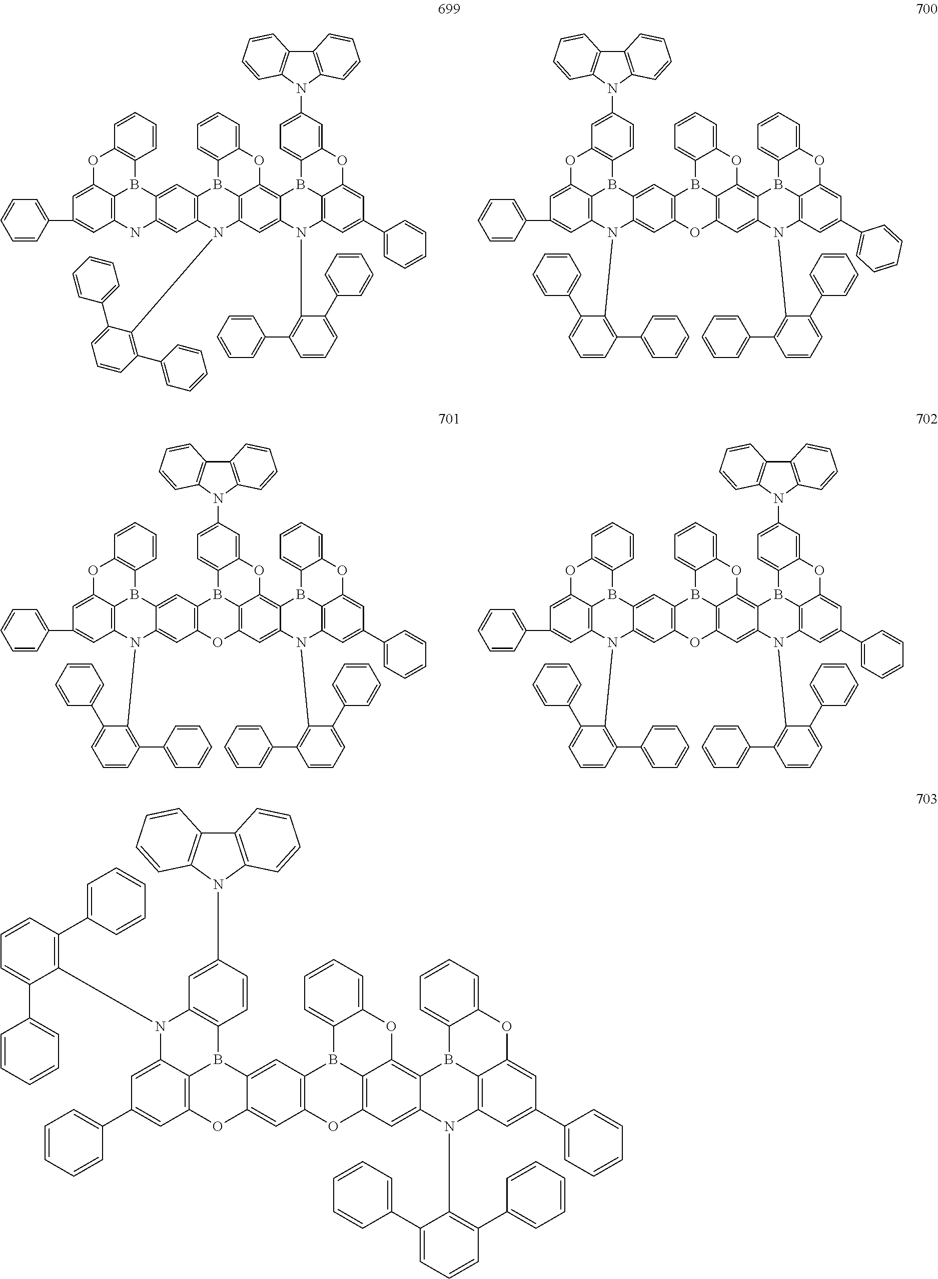 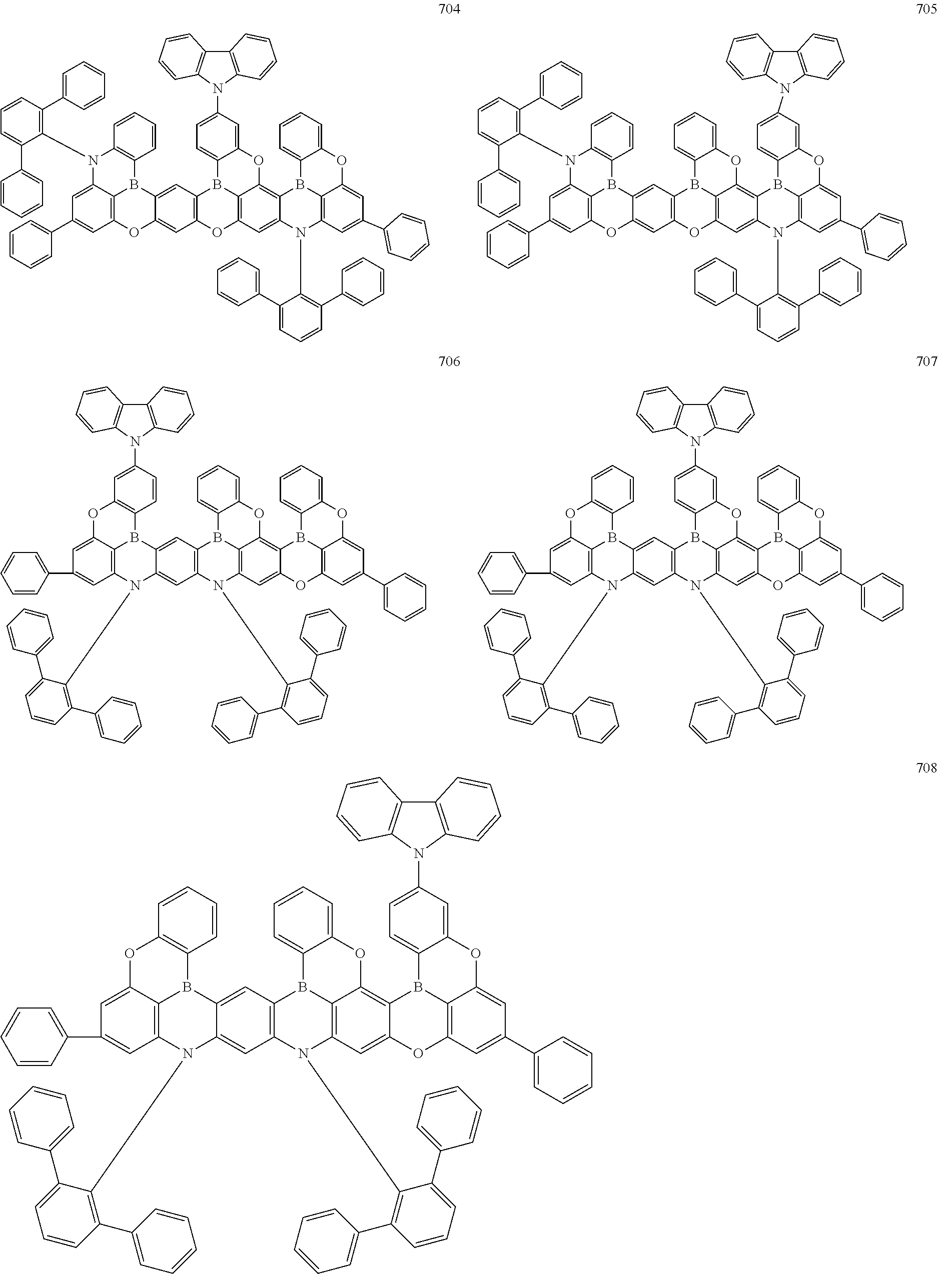 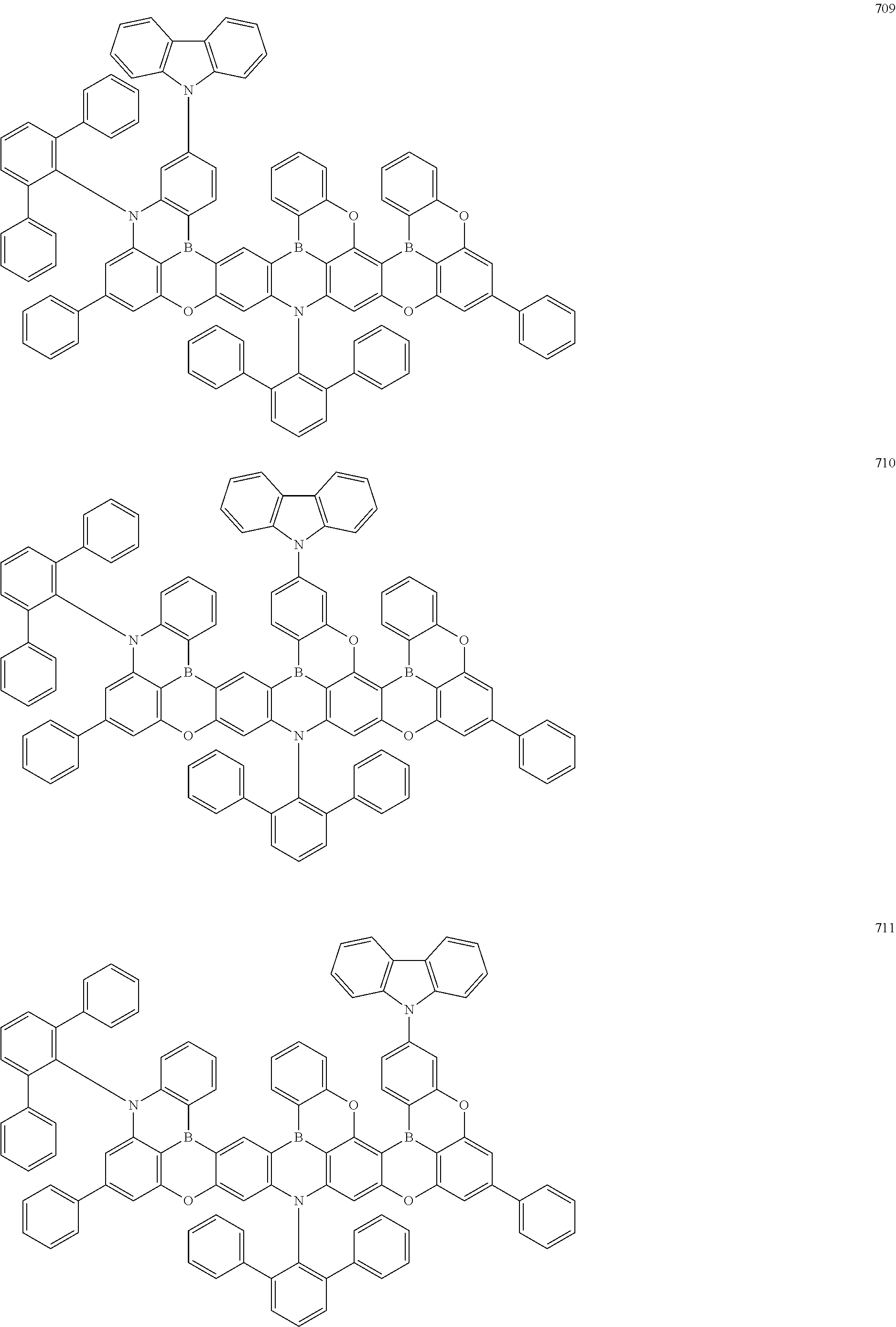 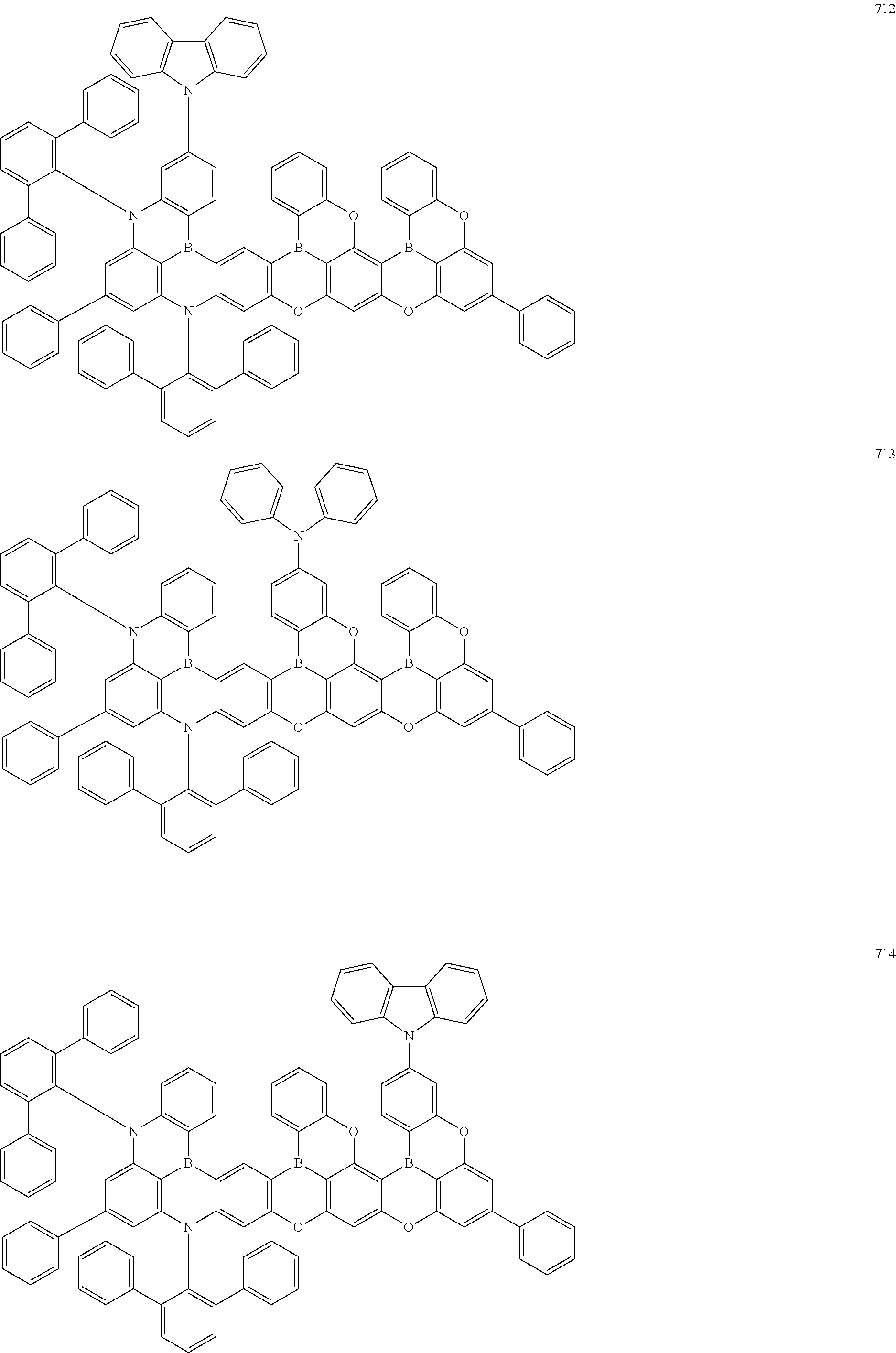 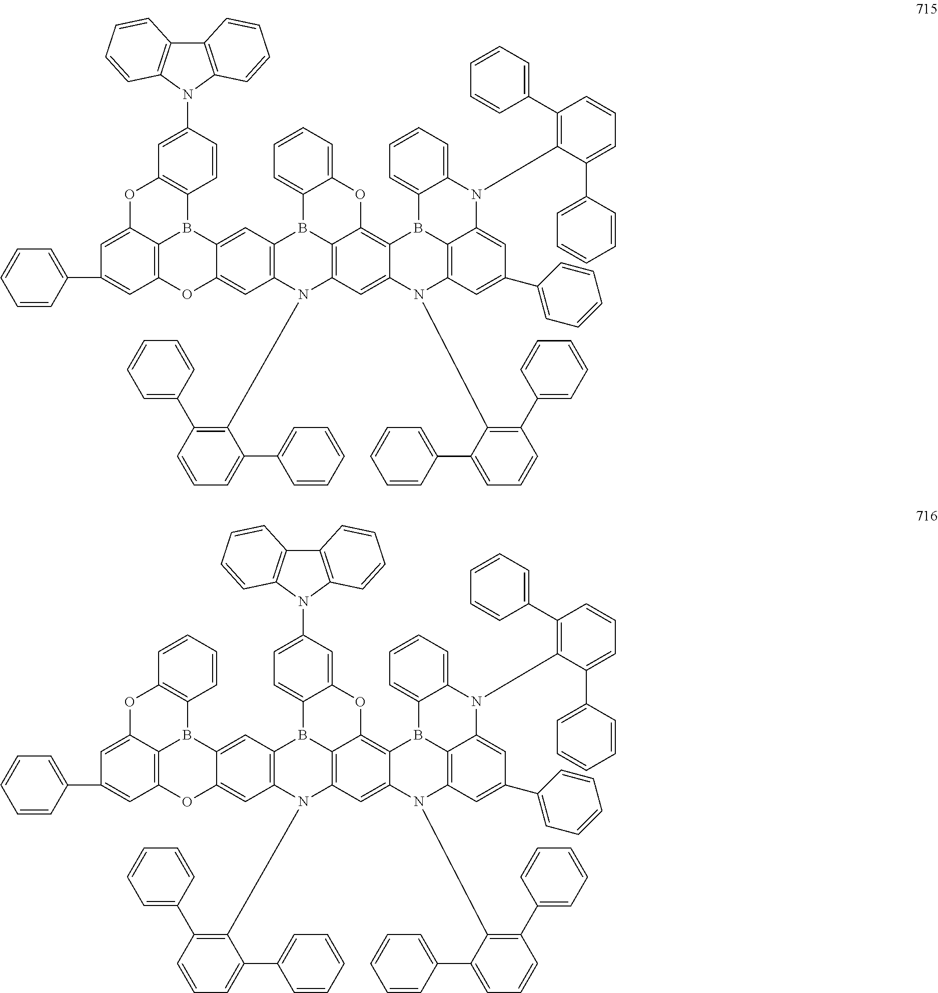 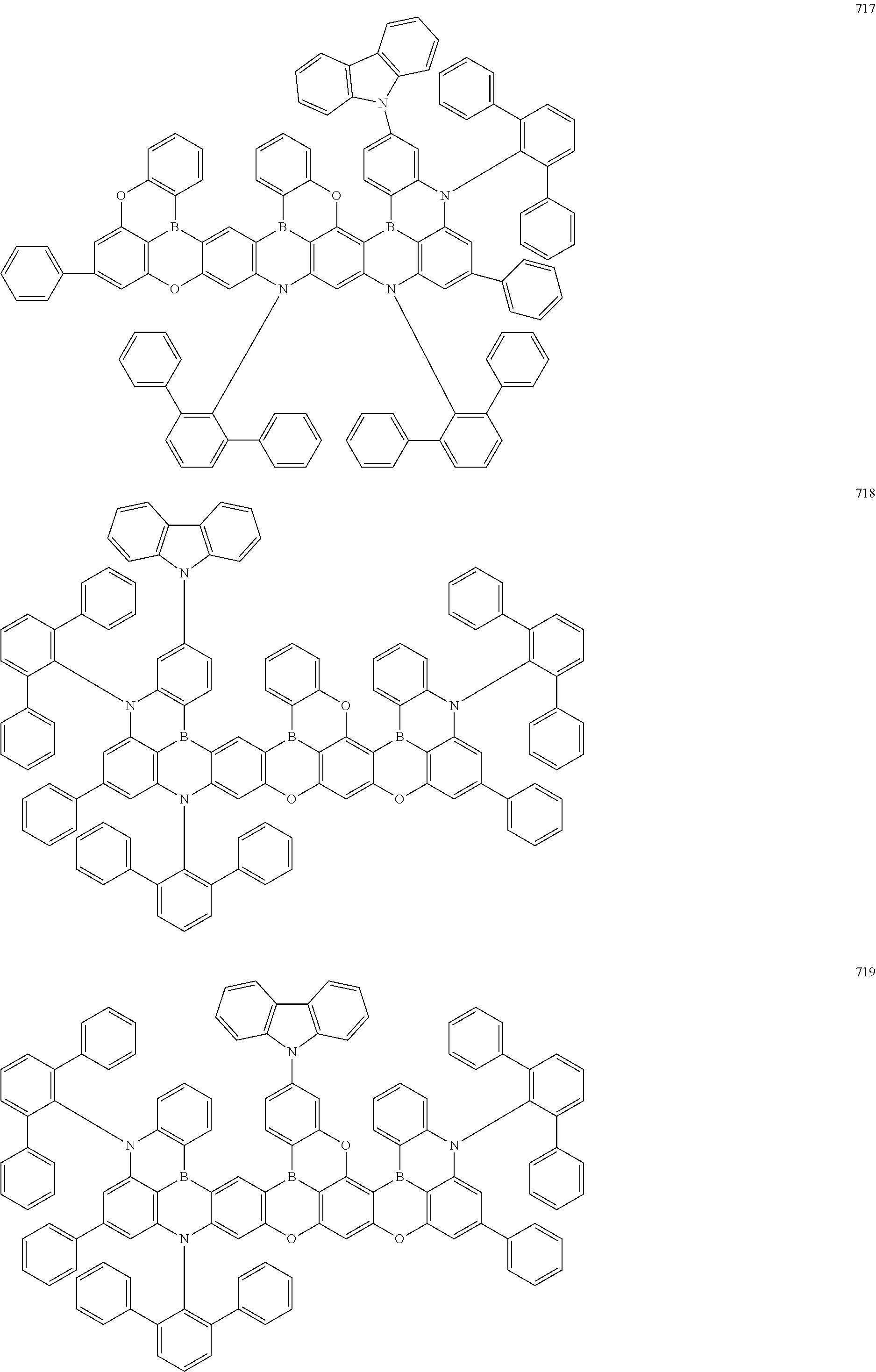 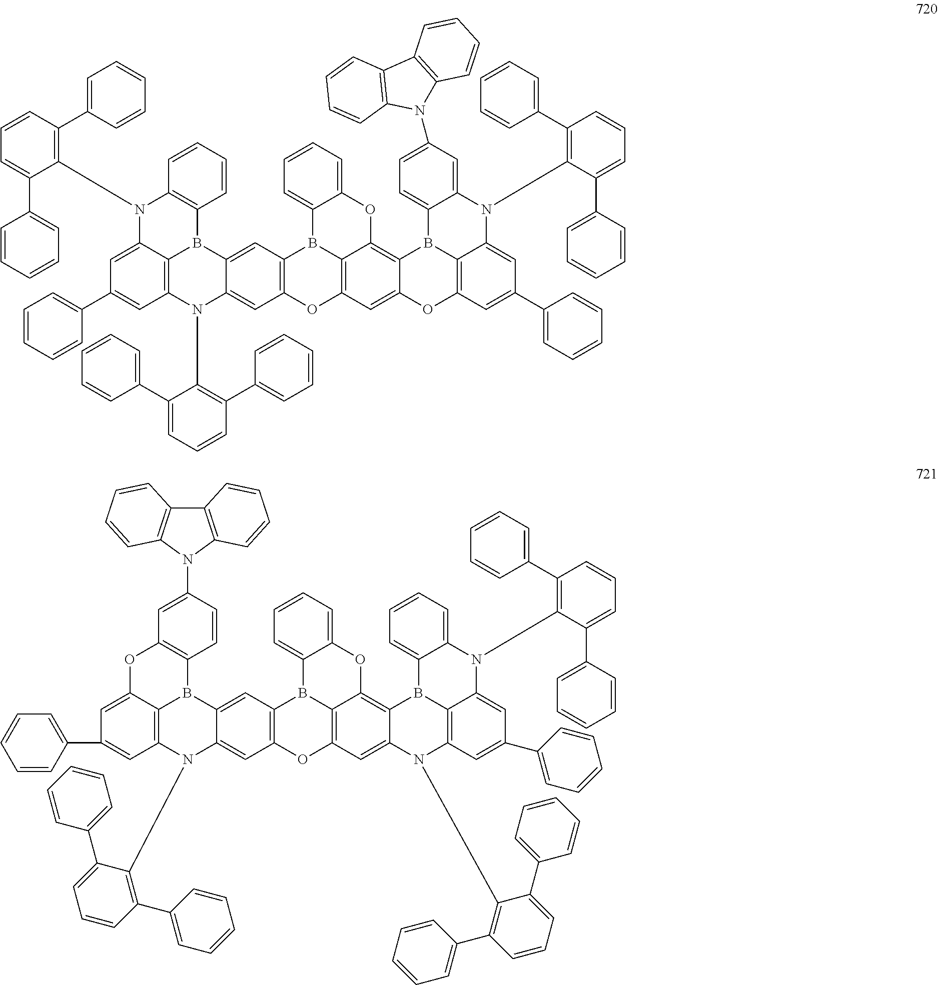 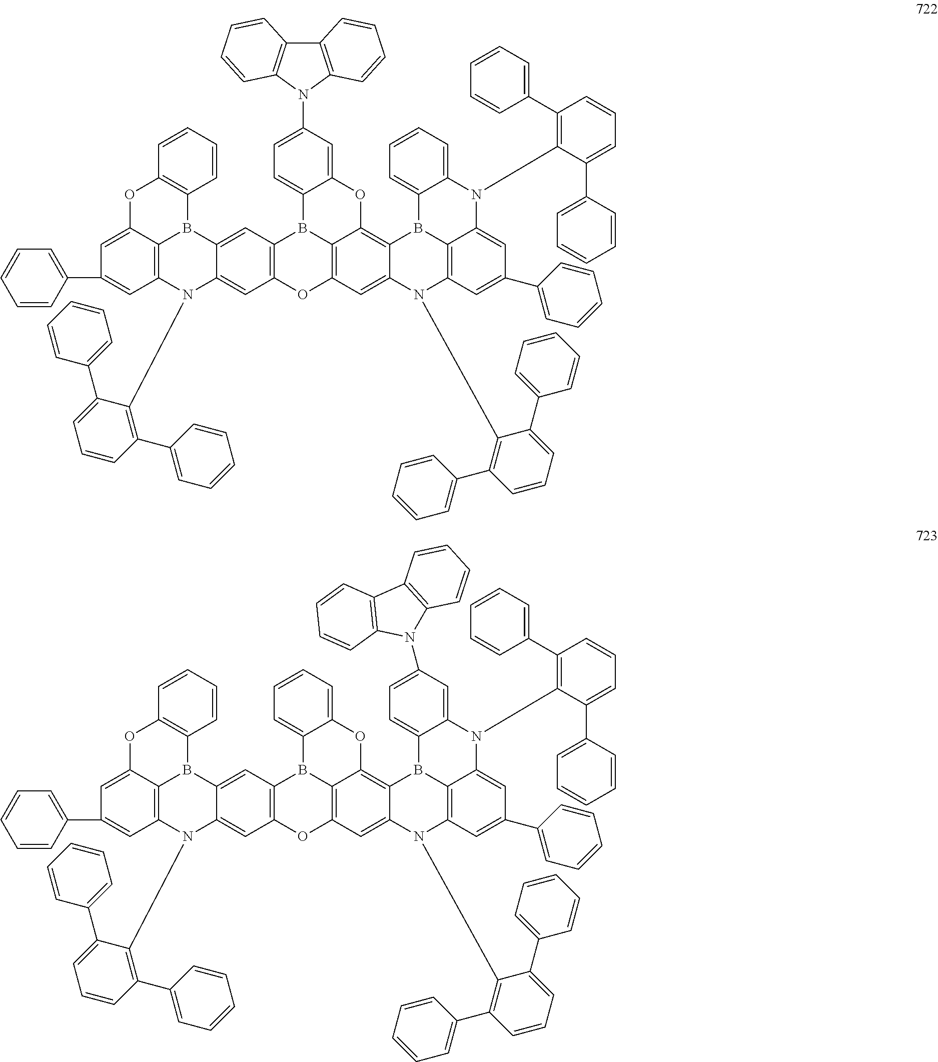 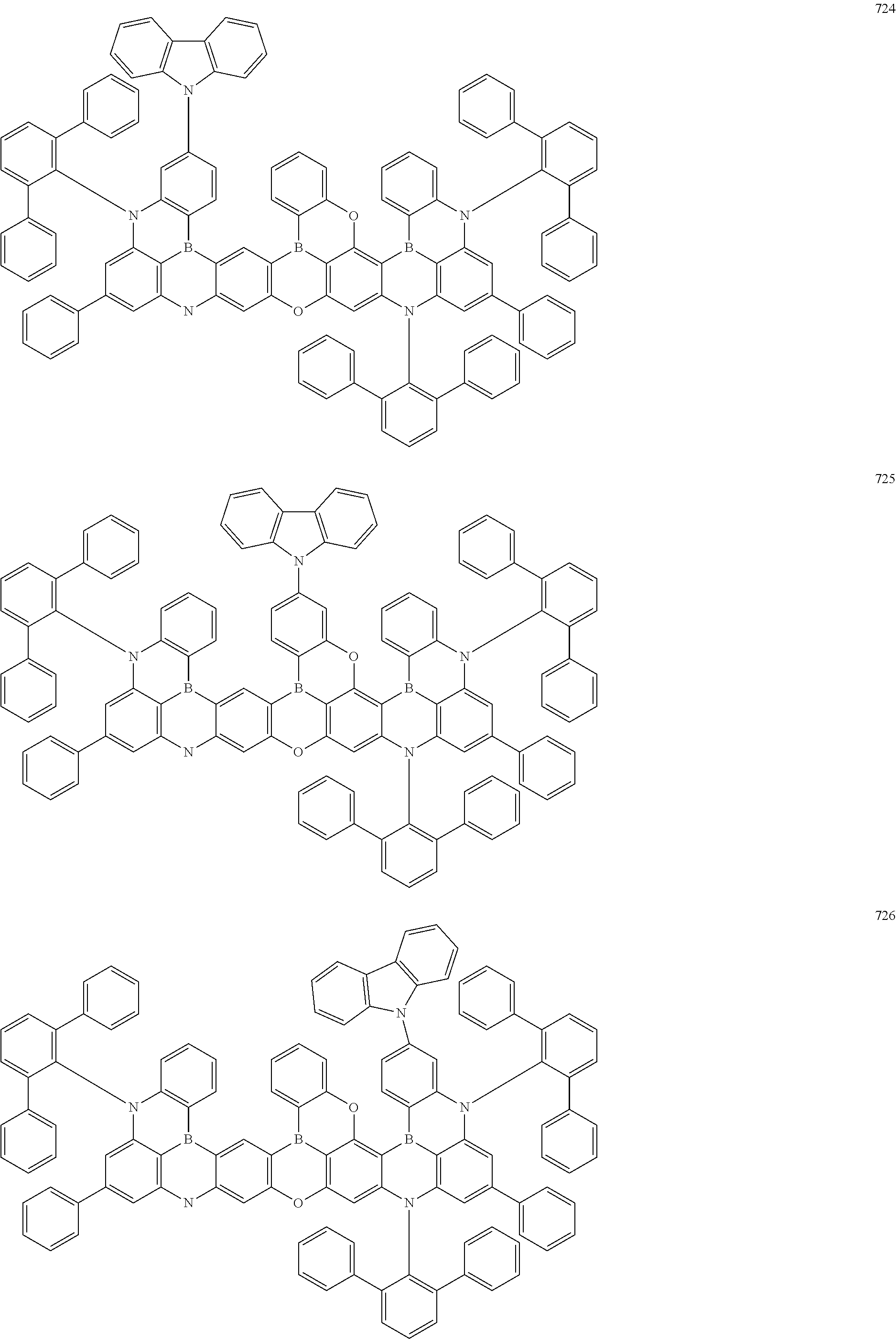 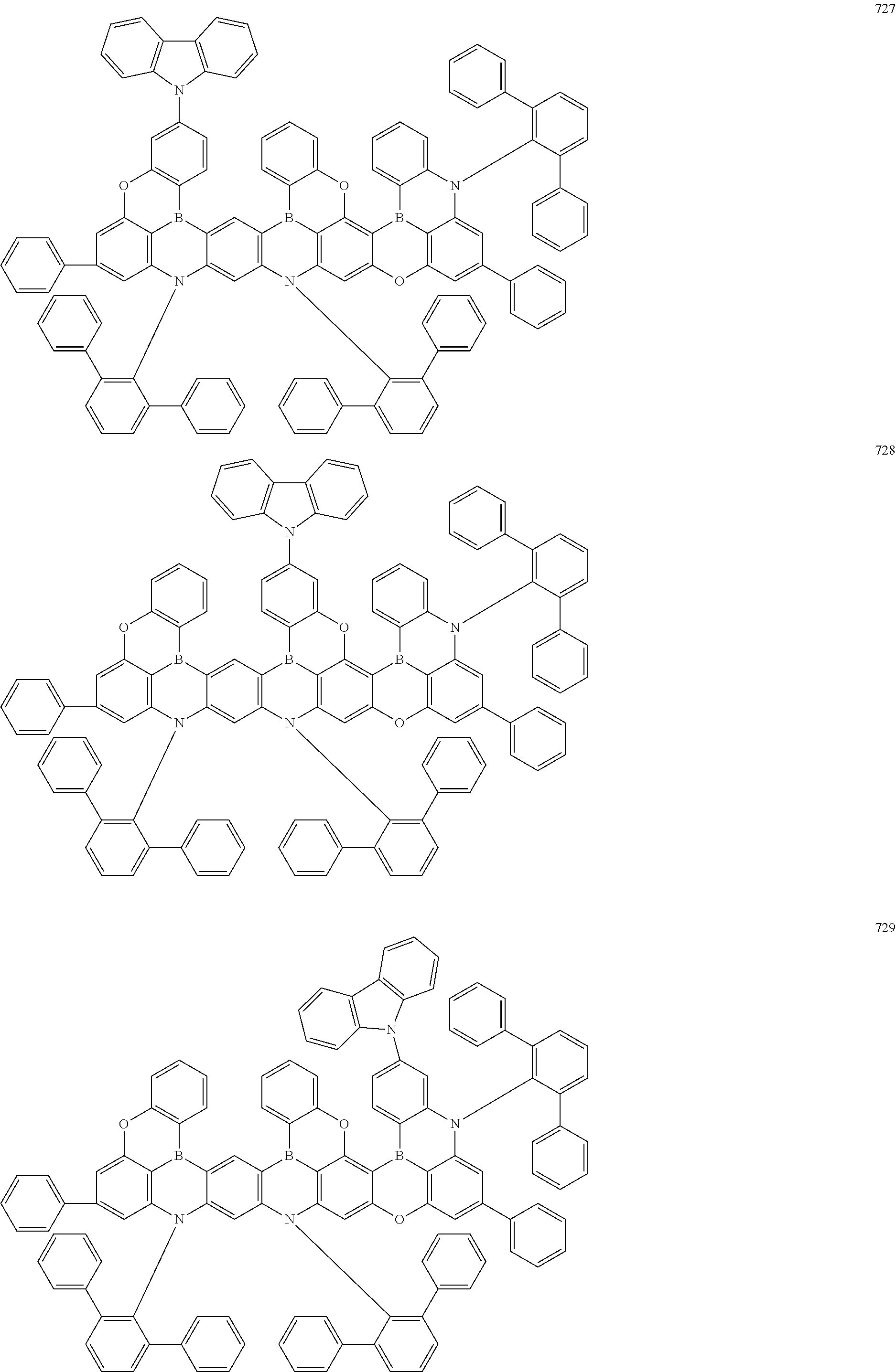 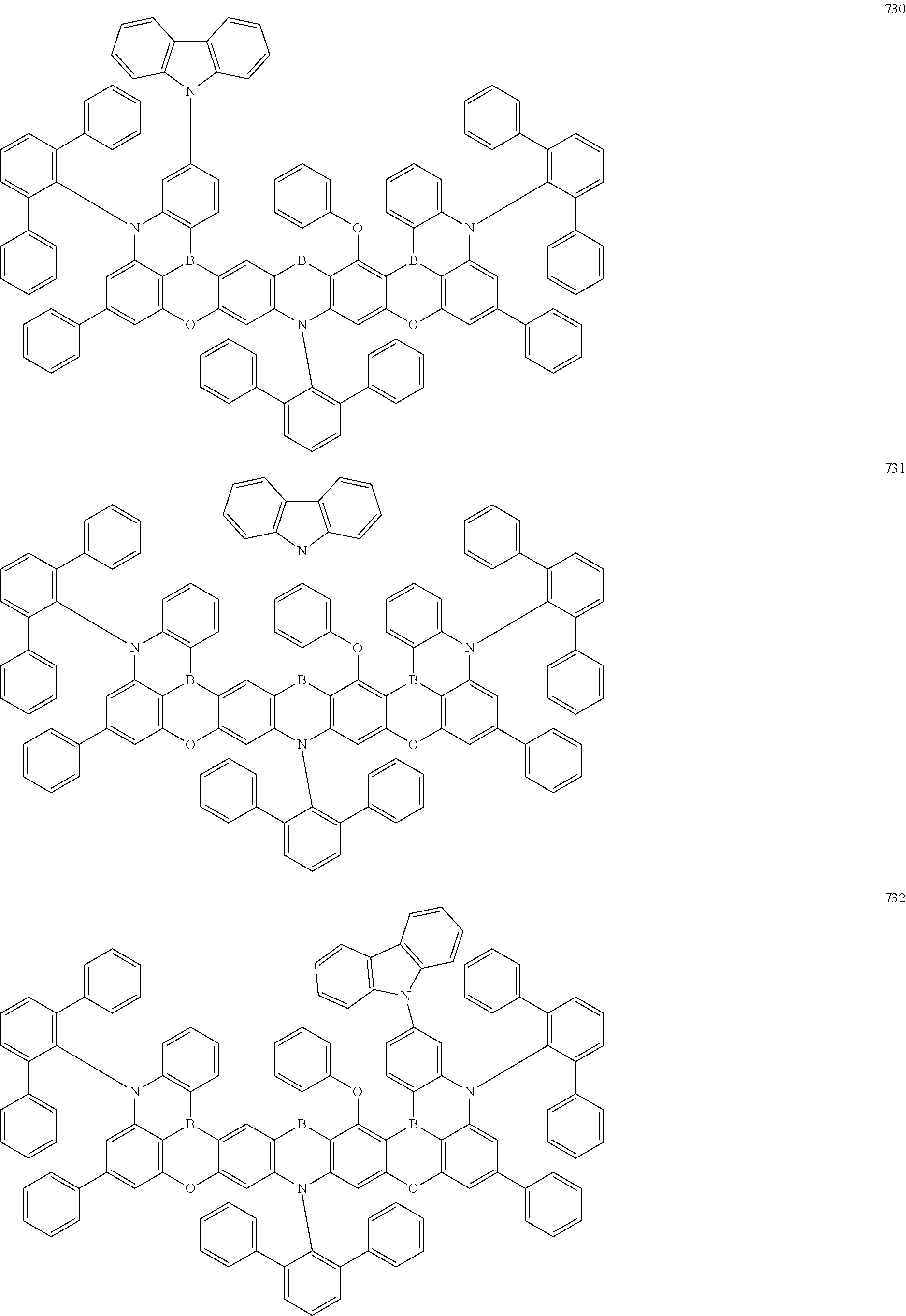 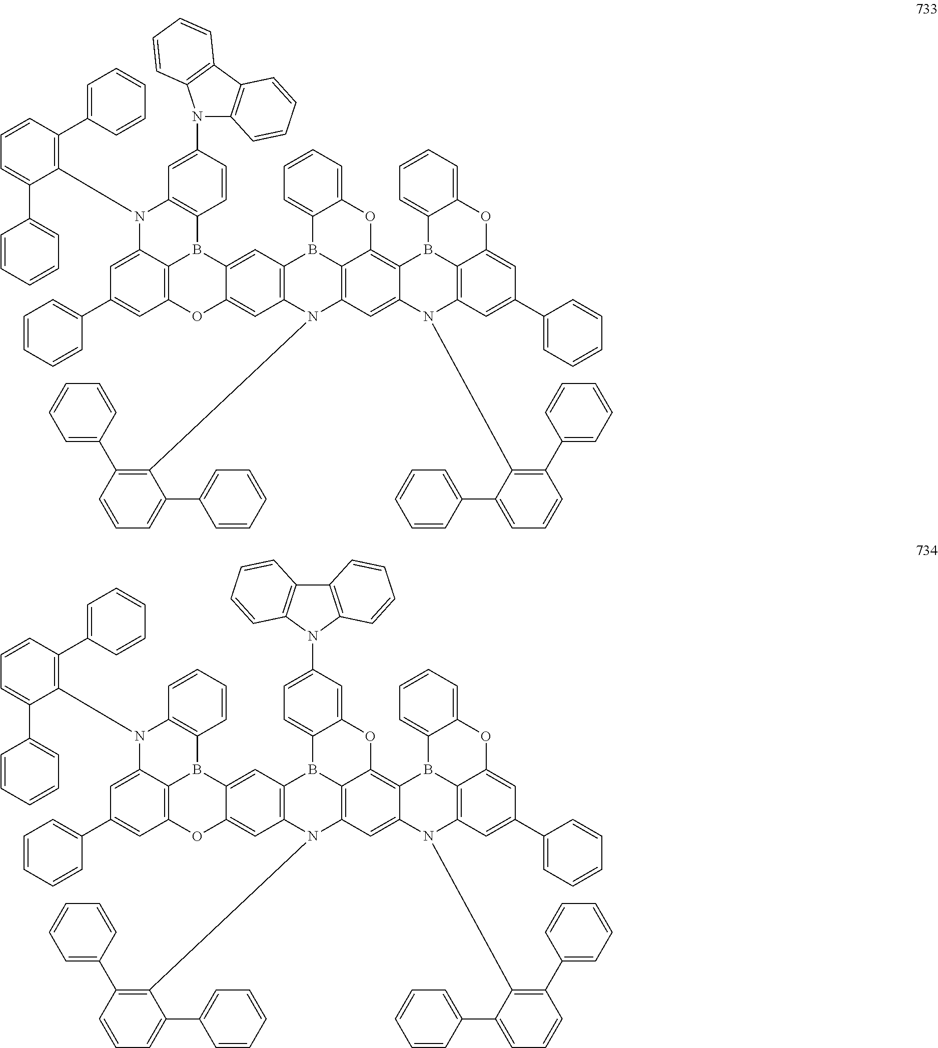 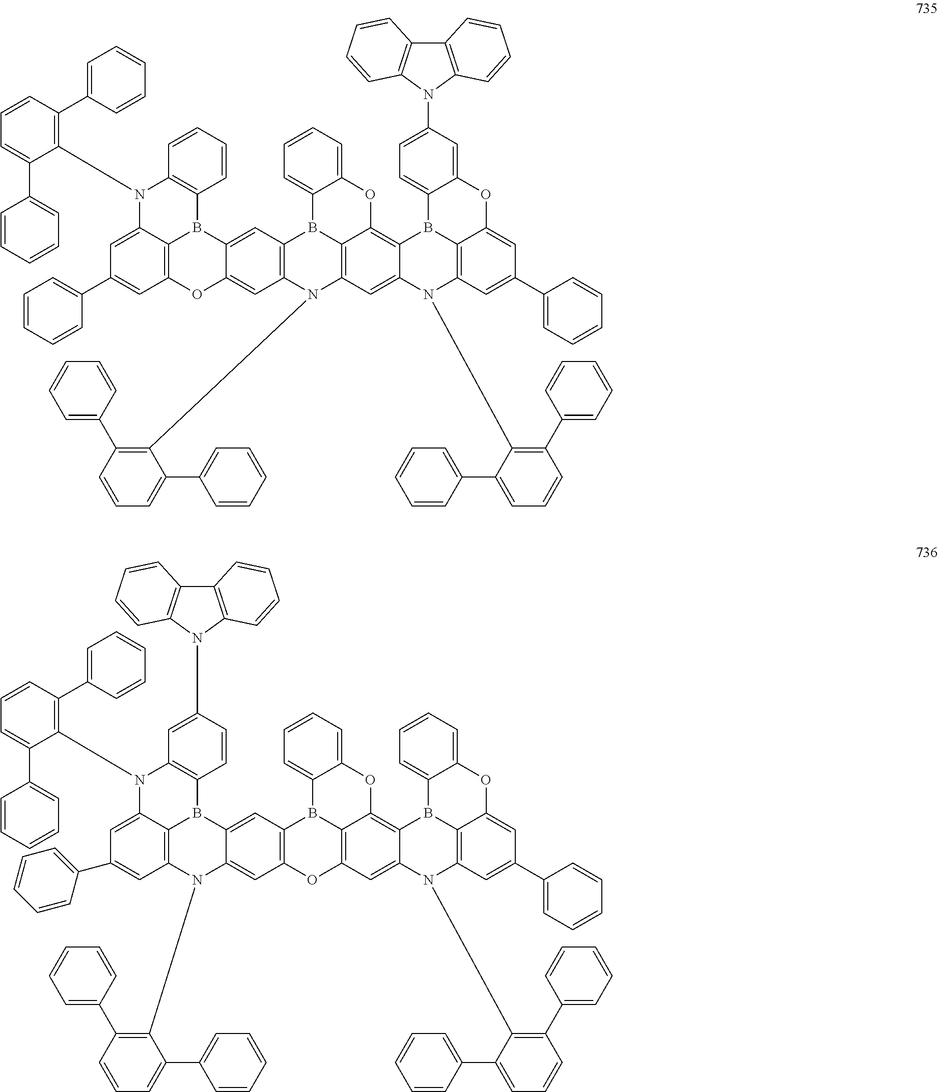 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc3c(c5c2B4c2ccccc2O5)B2c4ccc(-n5c6ccccc6c6ccccc65)cc4Oc4cc(-c5ccccc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2cc5c6c(c2B4c2ccccc2O3)Oc2ccccc2B6c2cc3c(cc2O5)N(c2c(-c4ccccc4)cccc2-c2ccccc2)c2cc(-c4ccccc4)cc4c2B3c2ccc(-n3c5ccccc5c5ccccc53)cc2N4c2c(-c3ccccc3)cccc2-c2ccccc2)cc1] 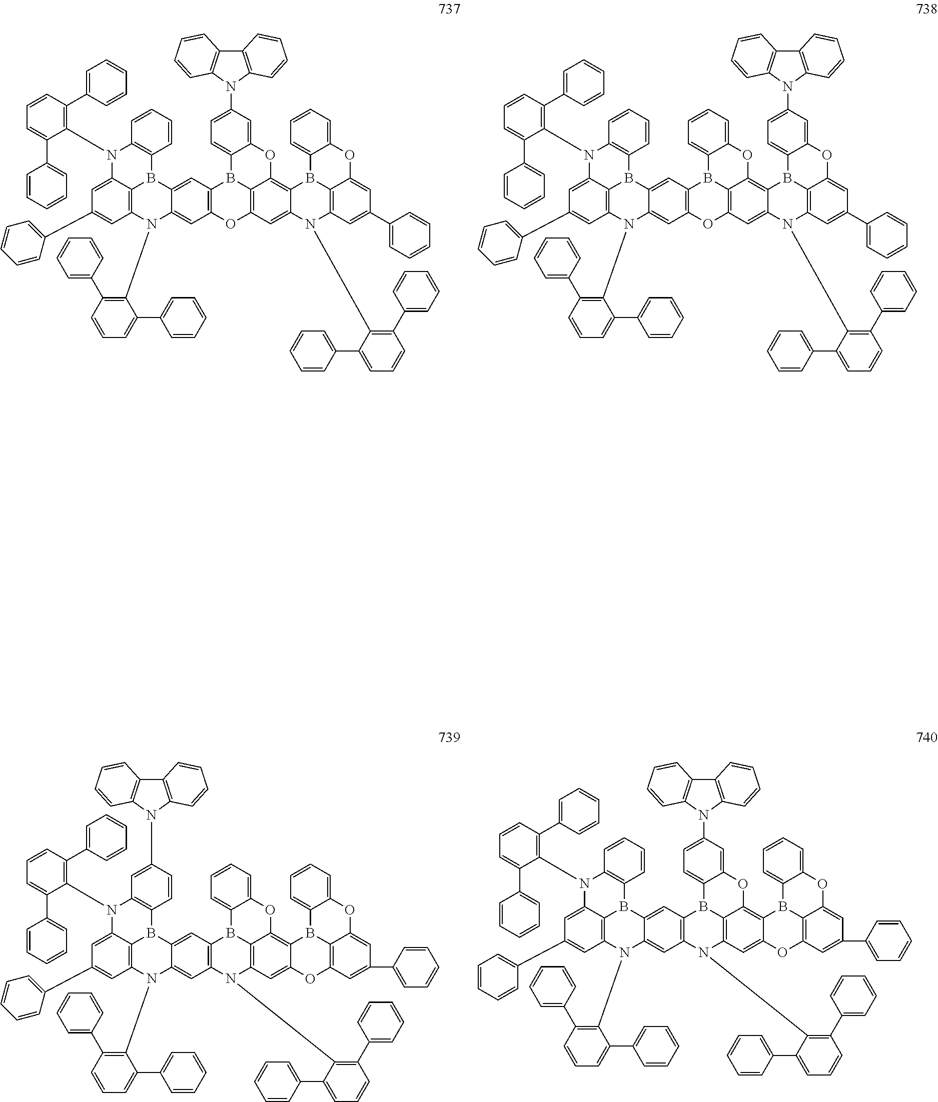 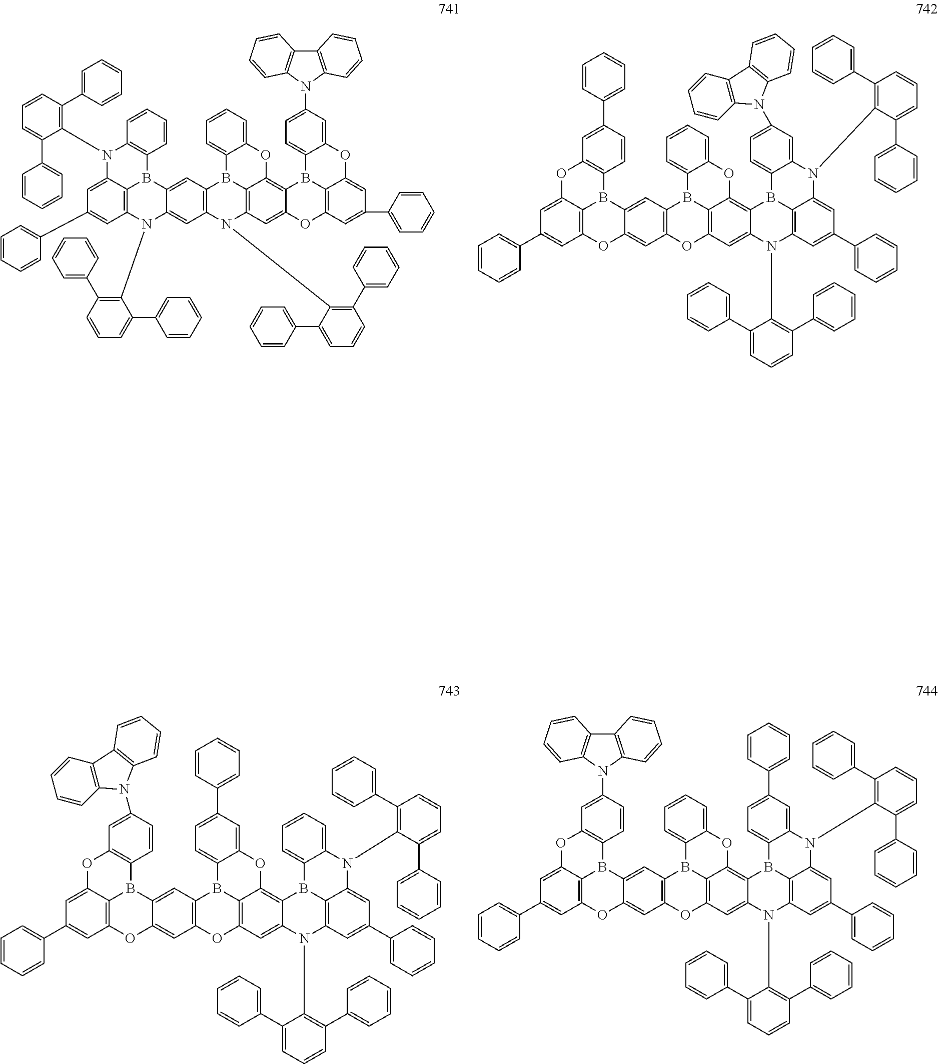 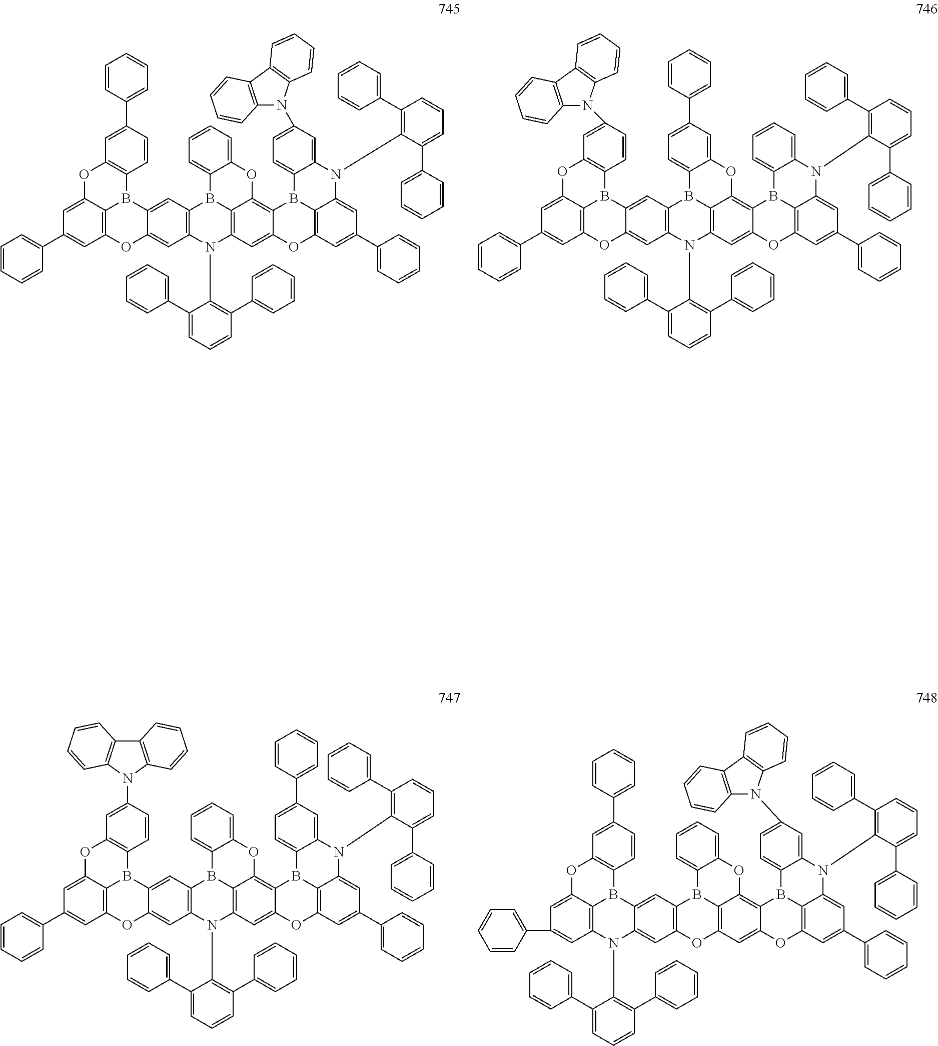 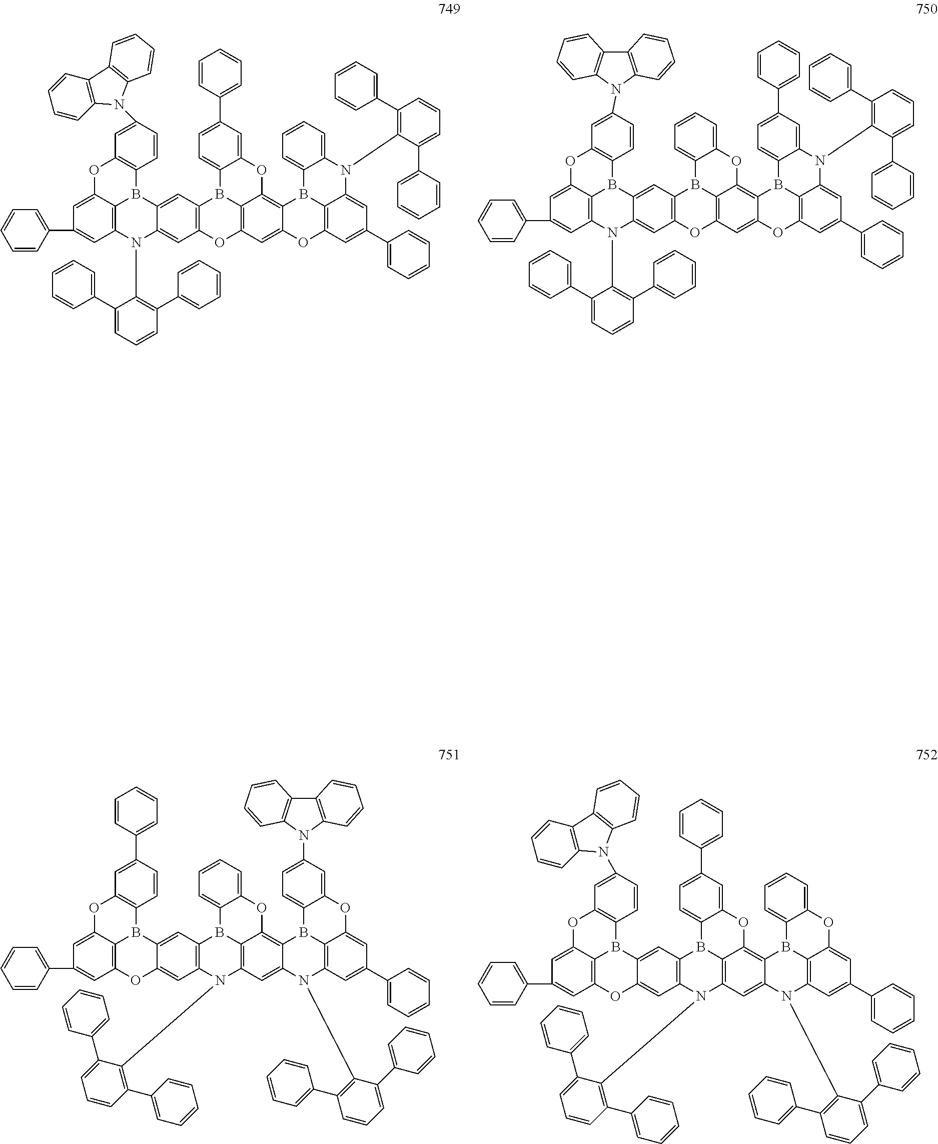 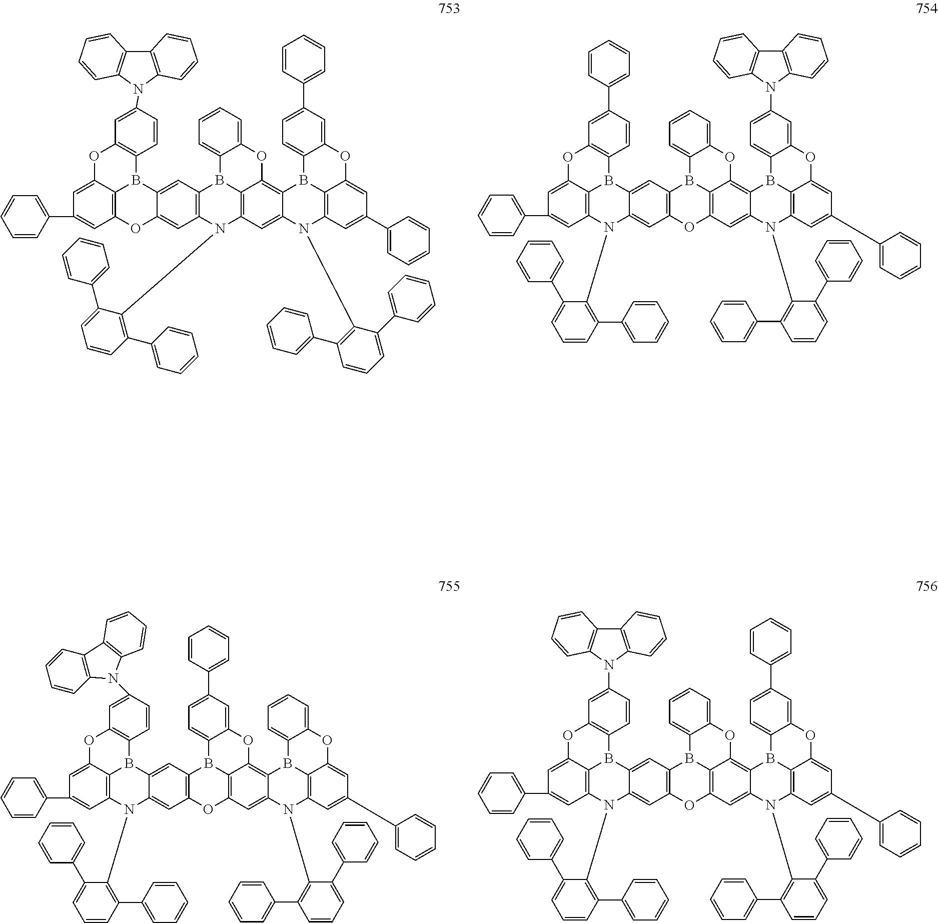 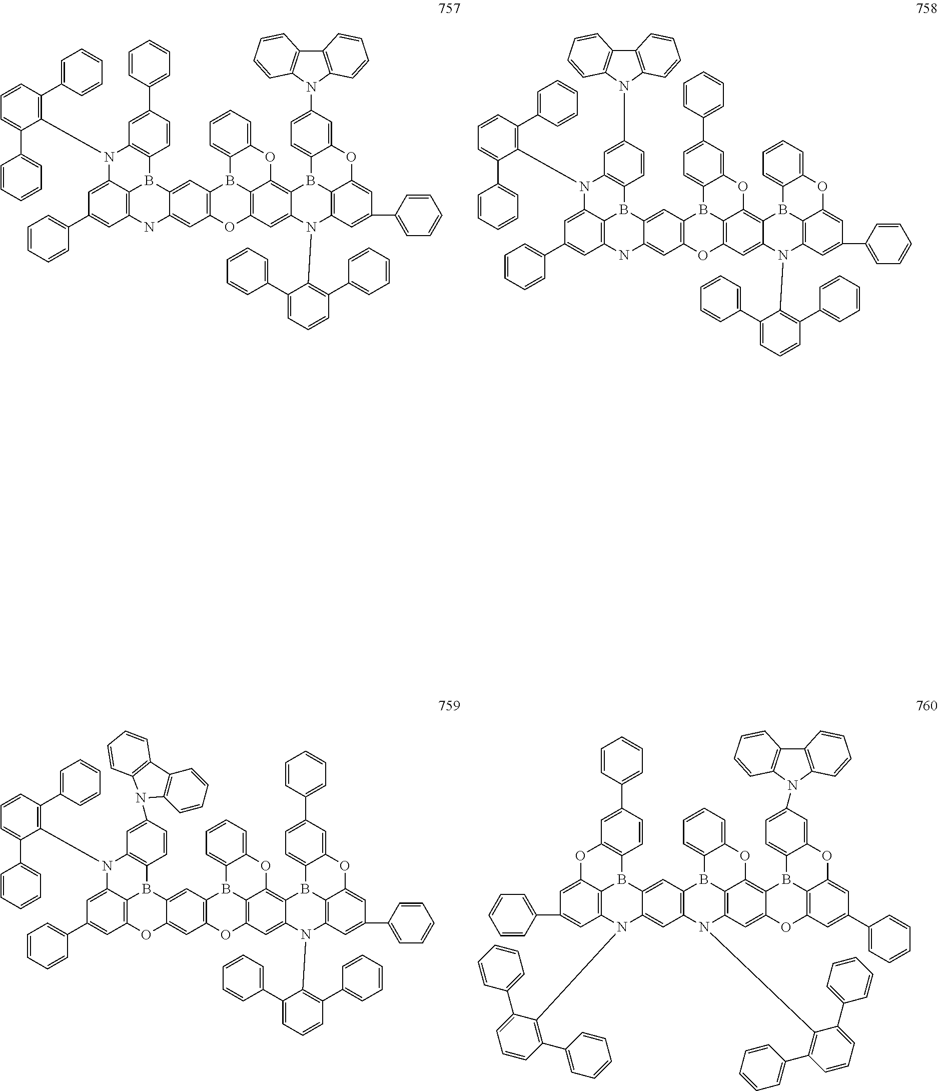 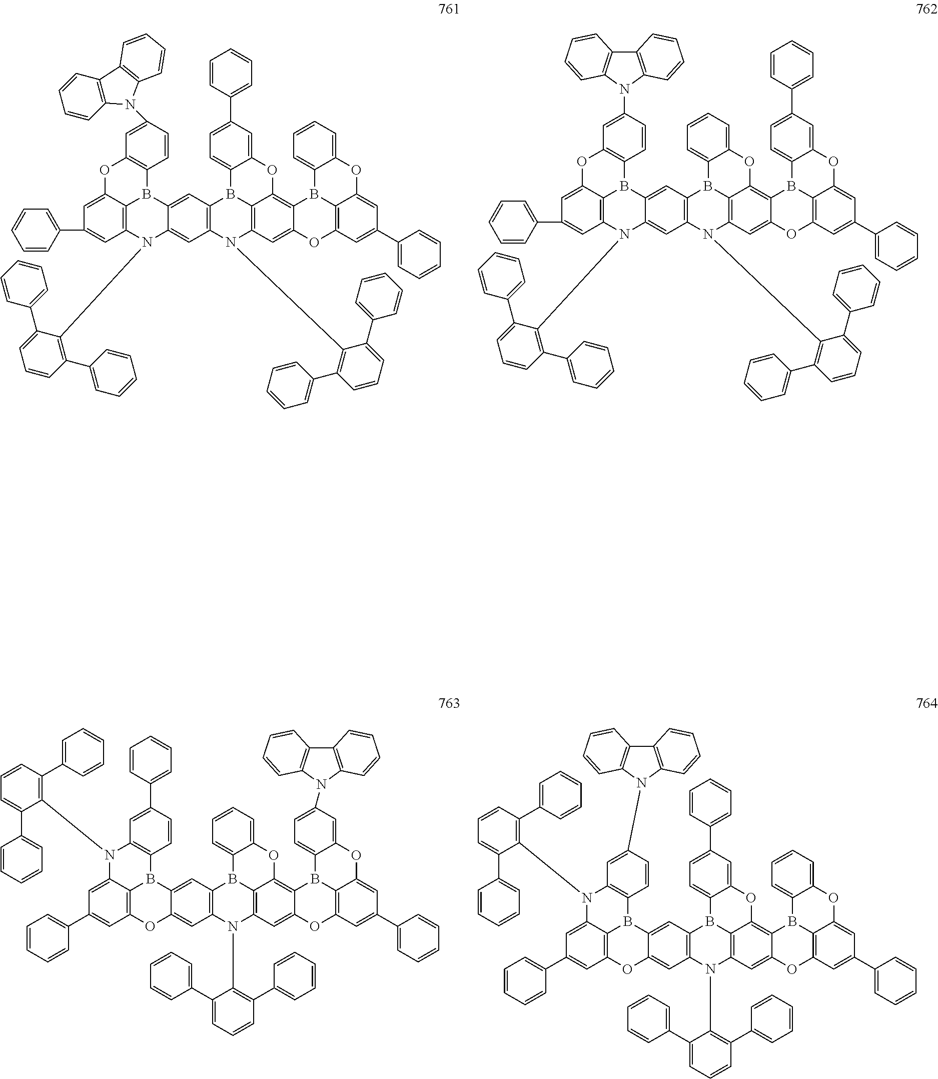 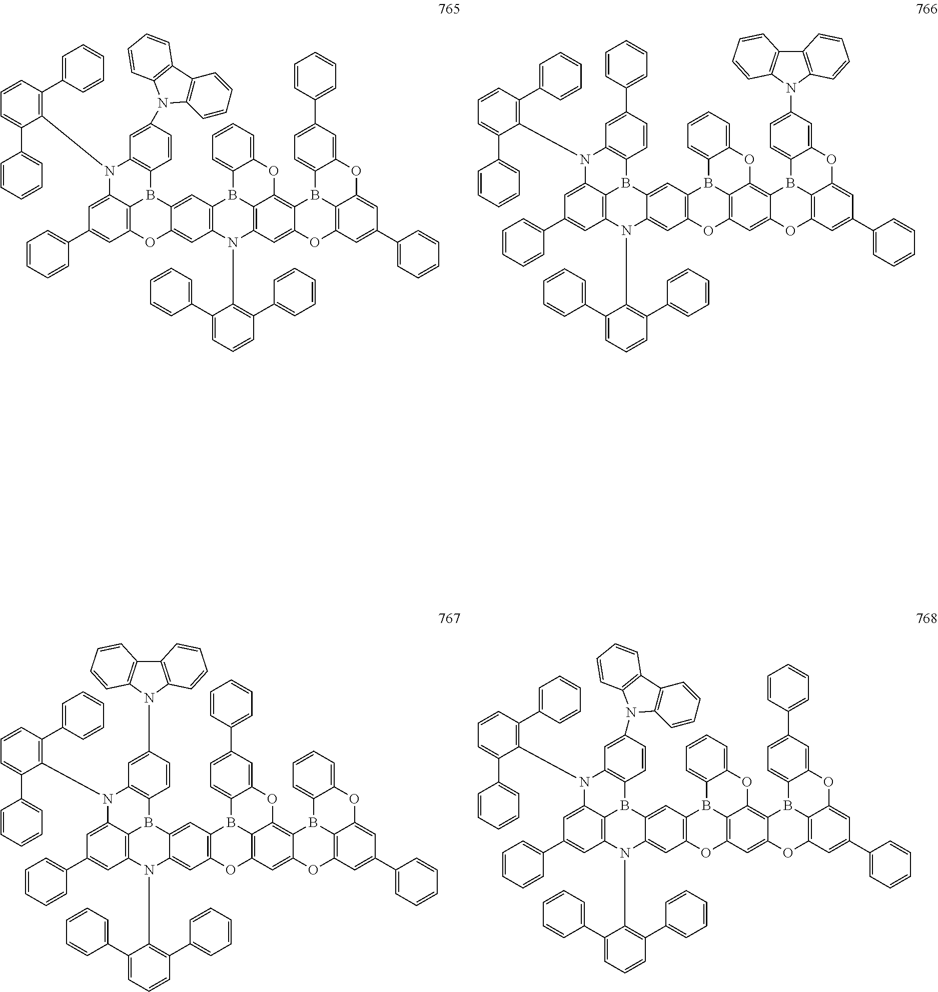 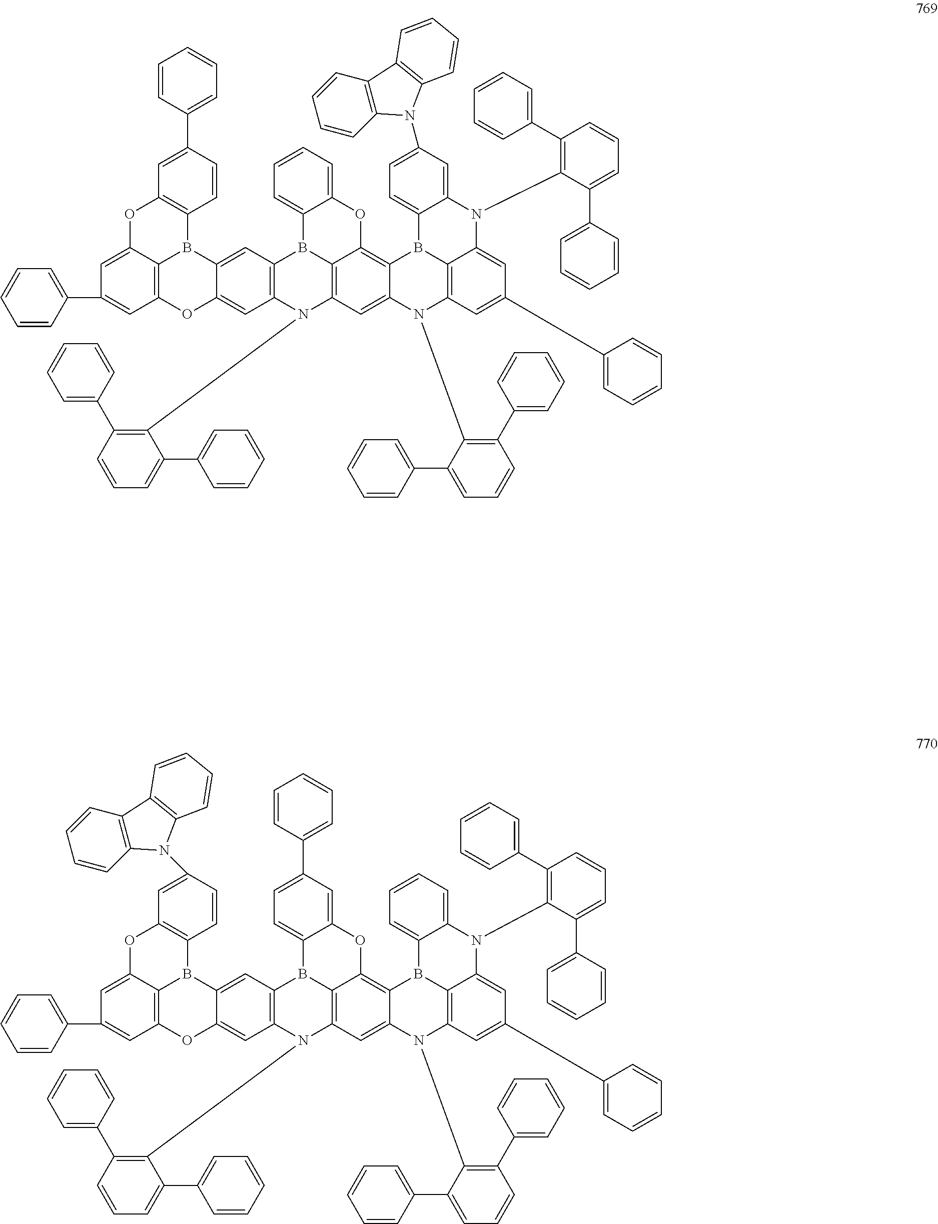 [SMILES: c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3Oc3cc(-c4ccccc4)cc(c32)O5)cc1] 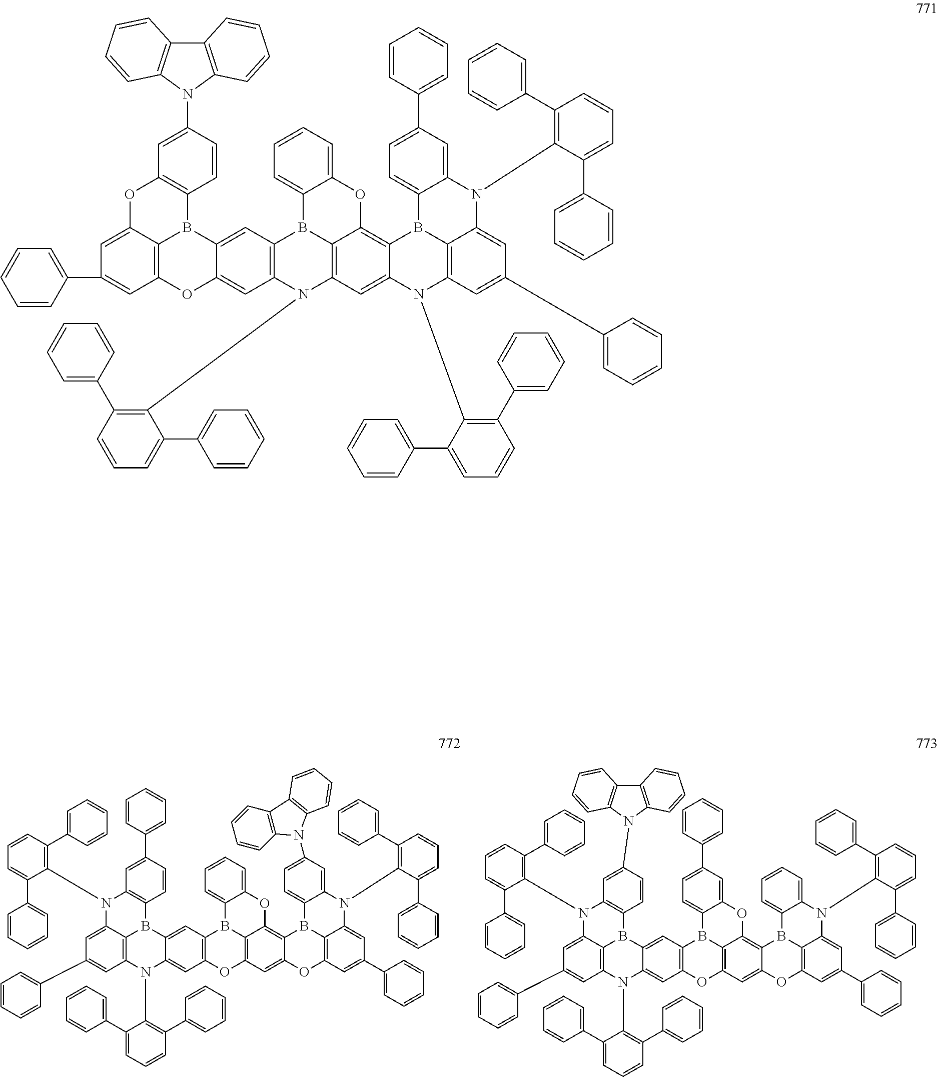 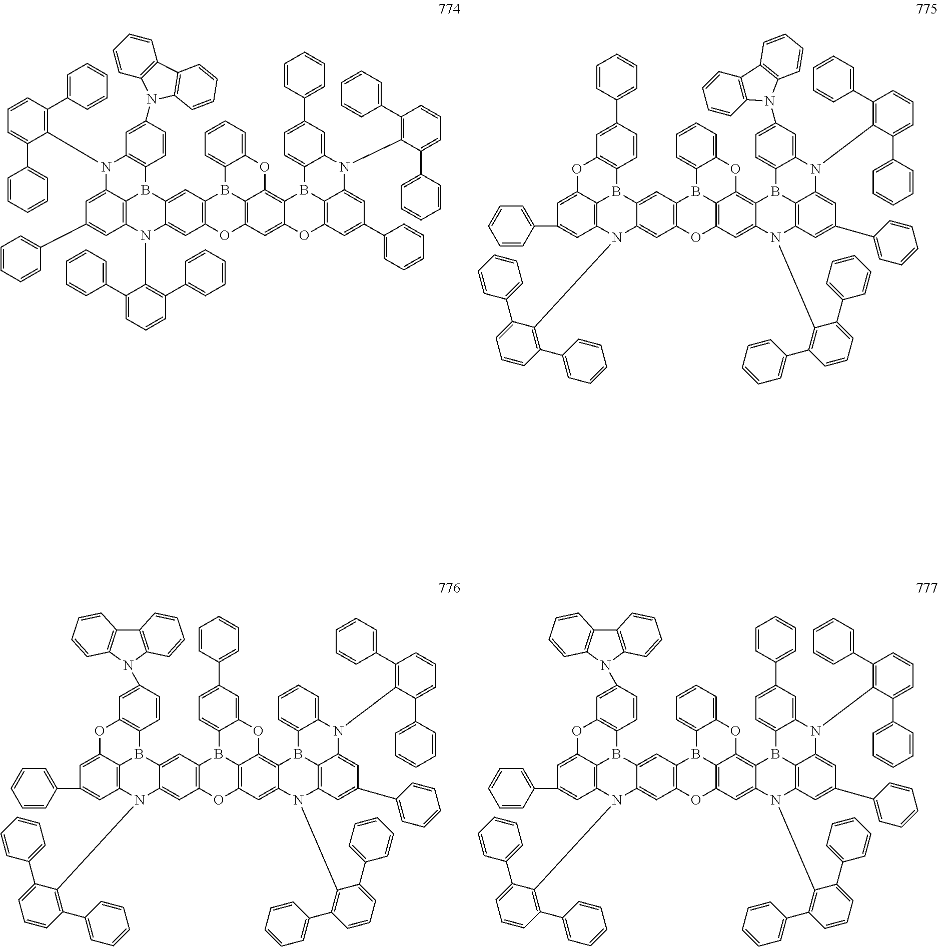 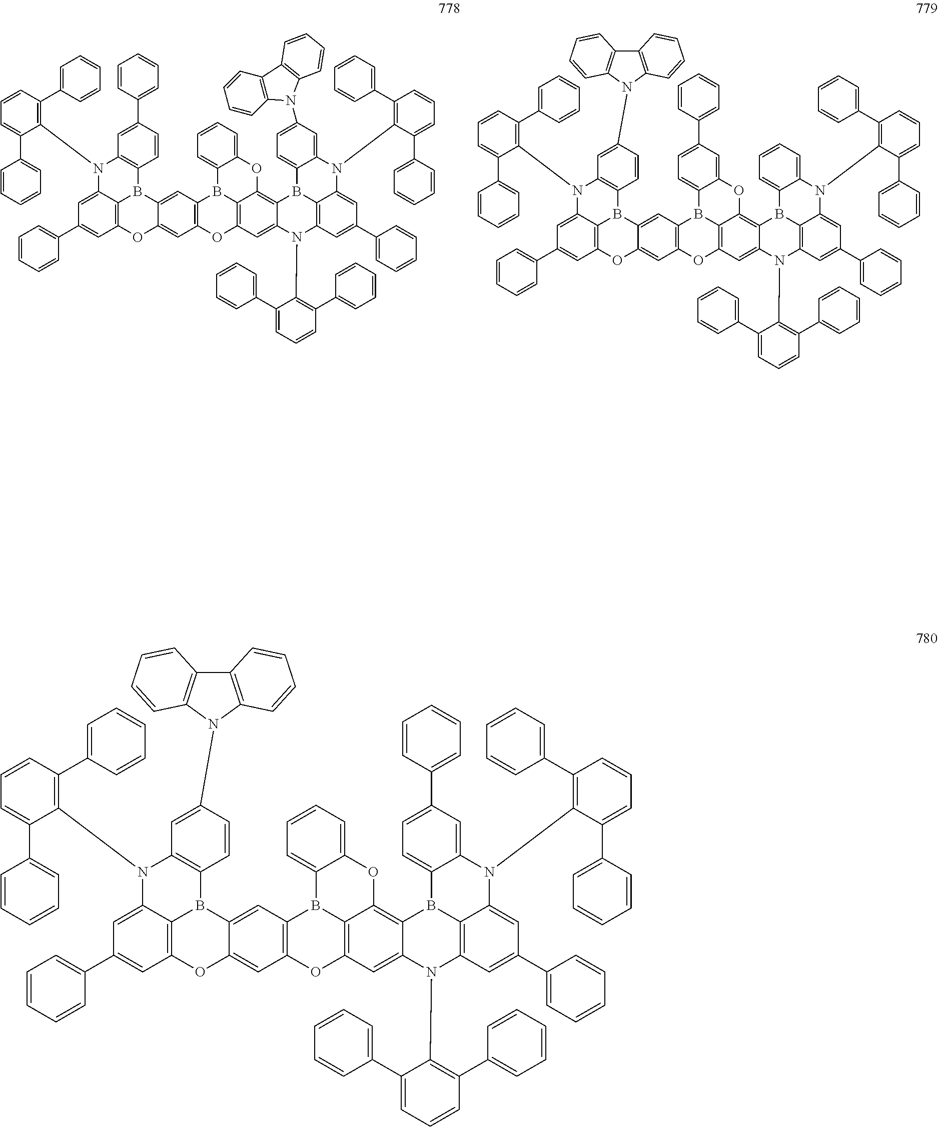 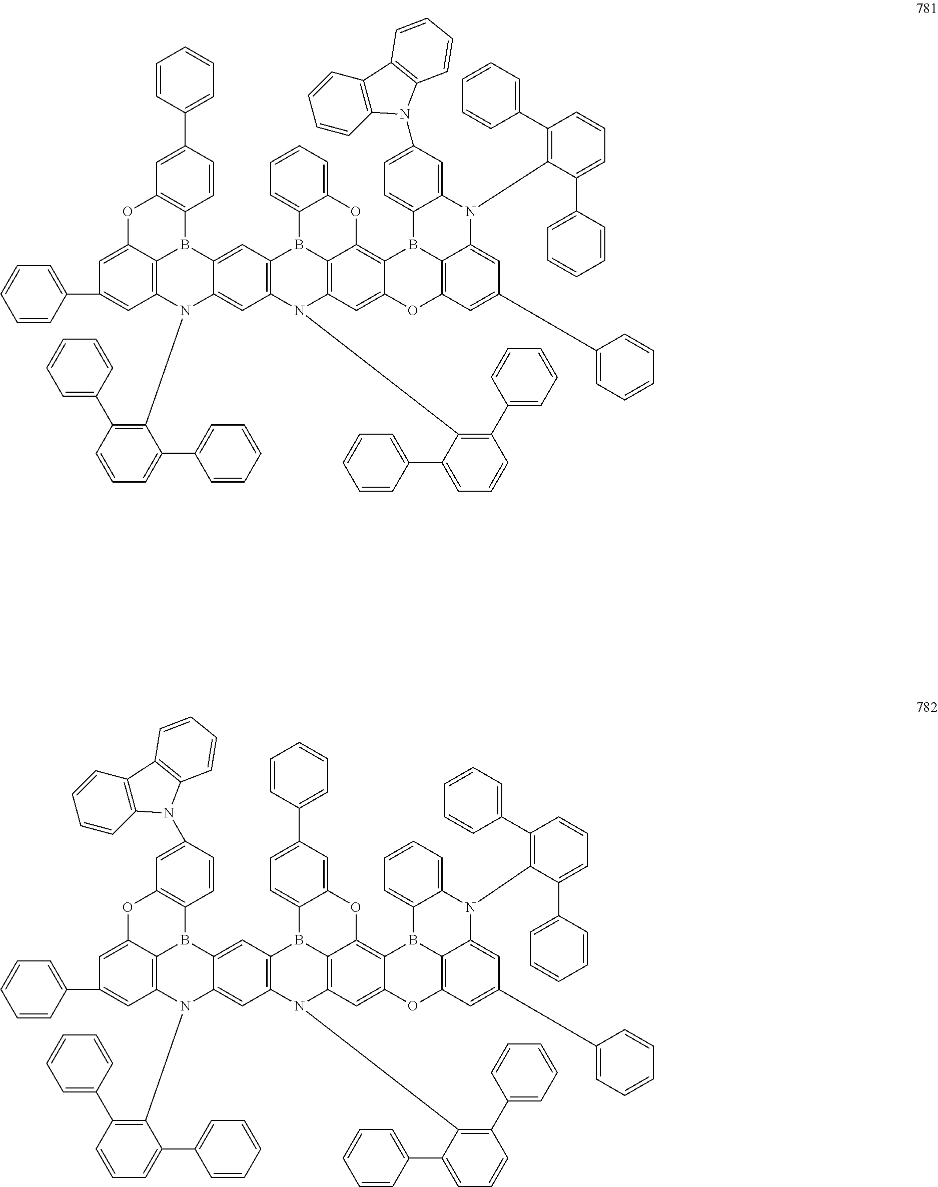 [SMILES: c1ccc(-c2ccc3c(c2)Oc2cc(-c4ccccc4)cc4c2B3c2cc3c(cc2N4c2c(-c4ccccc4)cccc2-c2ccccc2)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1 ; c1ccc(-c2ccc3c(c2)Oc2c4c(cc5c2B3c2cc3c(cc2N5c2c(-c5ccccc5)cccc2-c2ccccc2)N(c2c(-c5ccccc5)cccc2-c2ccccc2)c2cc(-c5ccccc5)cc5c2B3c2ccc(-n3c6ccccc6c6ccccc63)cc2O5)Oc2cc(-c3ccccc3)cc3c2B4c2ccccc2N3c2c(-c3ccccc3)cccc2-c2ccccc2)cc1] 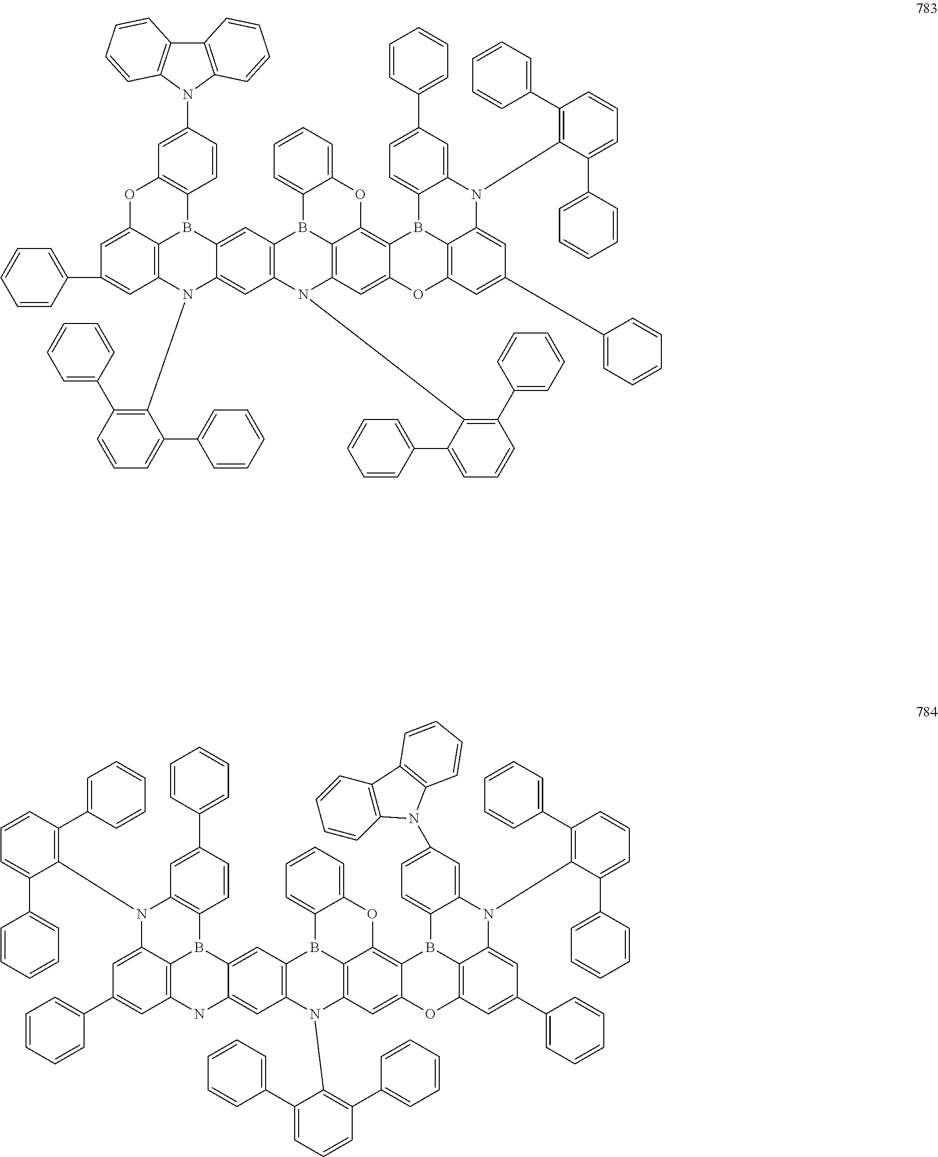 [SMILES: c1ccc(-c2ccc3c(c2)N(c2c(-c4ccccc4)cccc2-c2ccccc2)c2cc(-c4ccccc4)cc4c2B3c2c(cc3c5c2Oc2ccccc2B5c2cc5c(cc2N3c2c(-c3ccccc3)cccc2-c2ccccc2)N(c2c(-c3ccccc3)cccc2-c2ccccc2)c2cc(-c3ccccc3)cc3c2B5c2ccc(-n5c6ccccc6c6ccccc65)cc2O3)O4)cc1 ; c1ccc(-c2ccc3c(c2)N(c2c(-c4ccccc4)cccc2-c2ccccc2)c2cc(-c4ccccc4)cc4c2B3c2cc3c(cc2N4)N(c2c(-c4ccccc4)cccc2-c2ccccc2)c2cc4c(c5c2B3c2ccccc2O5)B2c3ccc(-n5c6ccccc6c6ccccc65)cc3N(c3c(-c5ccccc5)cccc3-c3ccccc3)c3cc(-c5ccccc5)cc(c32)O4)cc1] 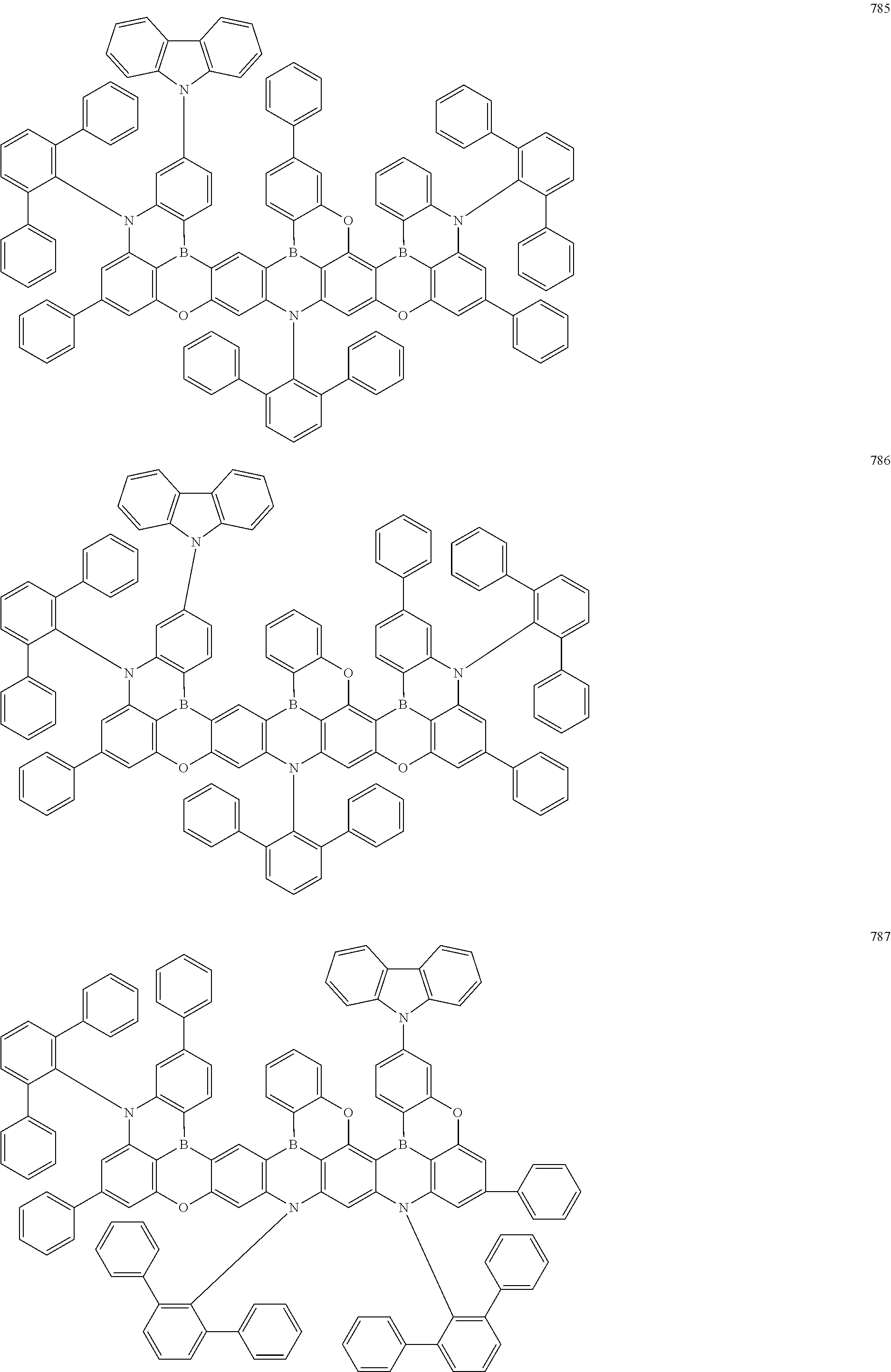 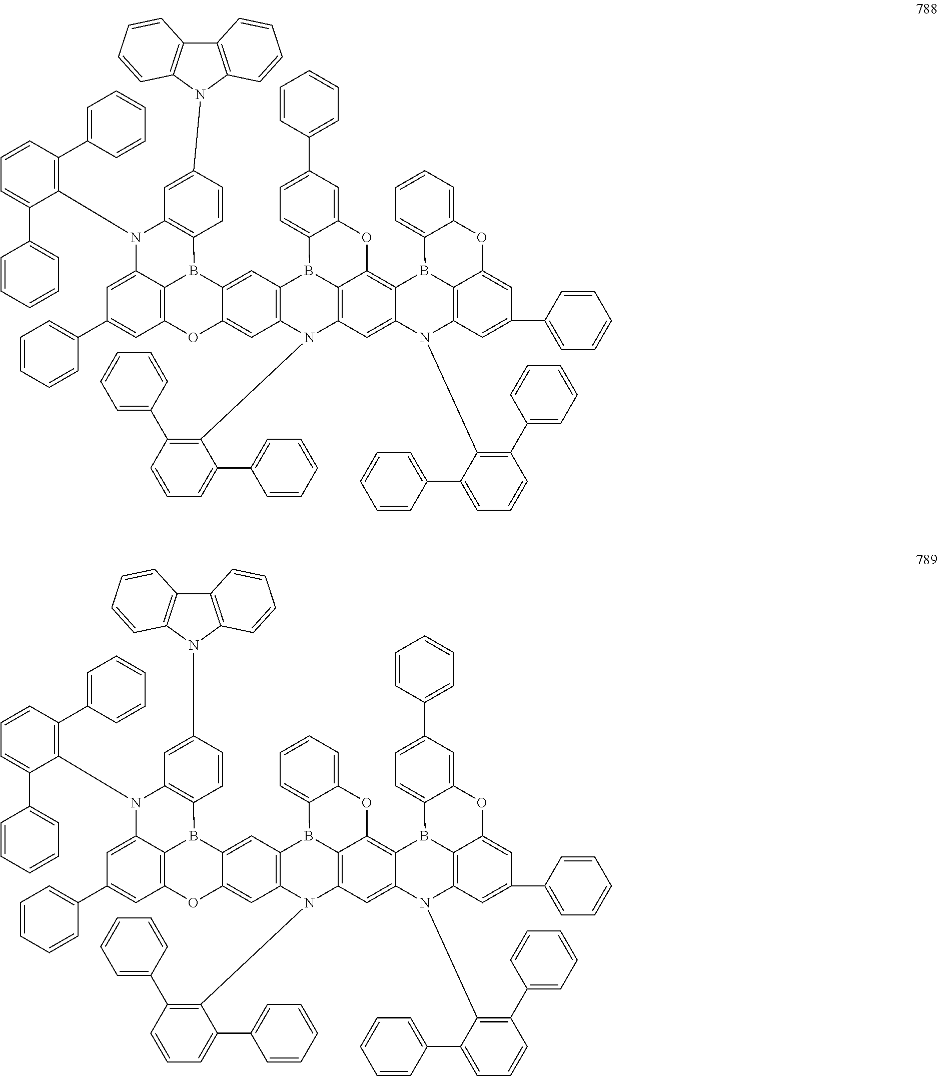 [SMILES: c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccc(-n4c6ccccc6c6ccccc64)cc3N(c3c(-c4ccccc4)cccc3-c3ccccc3)c3cc(-c4ccccc4)cc(c32)O5)cc1 ; c1ccc(-c2ccc3c(c2)Oc2cc(-c4ccccc4)cc4c2B3c2c(cc3c5c2Oc2ccccc2B5c2cc5c(cc2N3c2c(-c3ccccc3)cccc2-c2ccccc2)Oc2cc(-c3ccccc3)cc3c2B5c2ccc(-n5c6ccccc6c6ccccc65)cc2N3c2c(-c3ccccc3)cccc2-c2ccccc2)N4c2c(-c3ccccc3)cccc2-c2ccccc2)cc1] 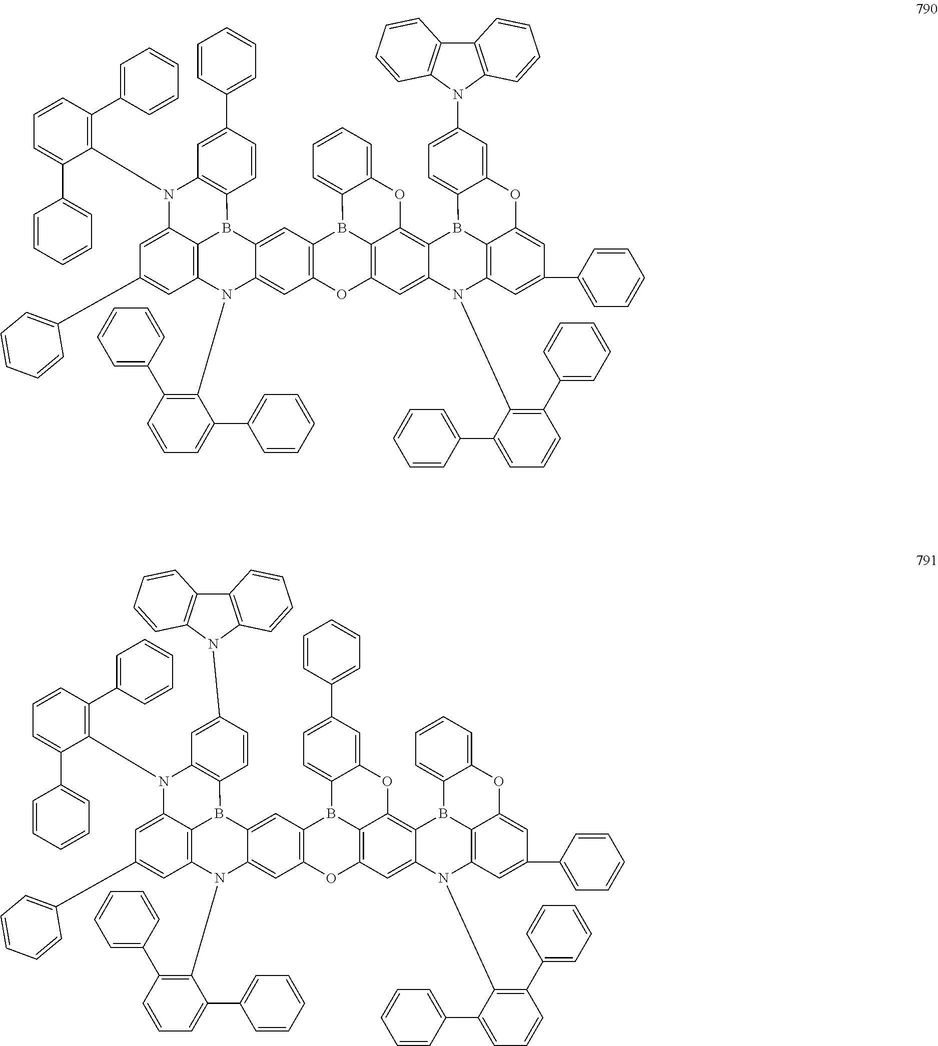 [SMILES: c1ccc(-c2ccc3c(c2)N(c2c(-c4ccccc4)cccc2-c2ccccc2)c2cc(-c4ccccc4)cc4c2B3c2cc3c(cc2N4c2c(-c4ccccc4)cccc2-c2ccccc2)Oc2cc4c(c5c2B3c2ccccc2O5)B2c3ccc(-n5c6ccccc6c6ccccc65)cc3Oc3cc(-c5ccccc5)cc(c32)N4c2c(-c3ccccc3)cccc2-c2ccccc2)cc1 ; c1ccc(-c2ccc3c(c2)Oc2c4c(cc5c2B2c6ccccc6Oc6cc(-c7ccccc7)cc(c62)N5c2c(-c5ccccc5)cccc2-c2ccccc2)Oc2cc5c(cc2B34)B2c3ccc(-n4c6ccccc6c6ccccc64)cc3N(c3c(-c4ccccc4)cccc3-c3ccccc3)c3cc(-c4ccccc4)cc(c32)N5c2c(-c3ccccc3)cccc2-c2ccccc2)cc1] 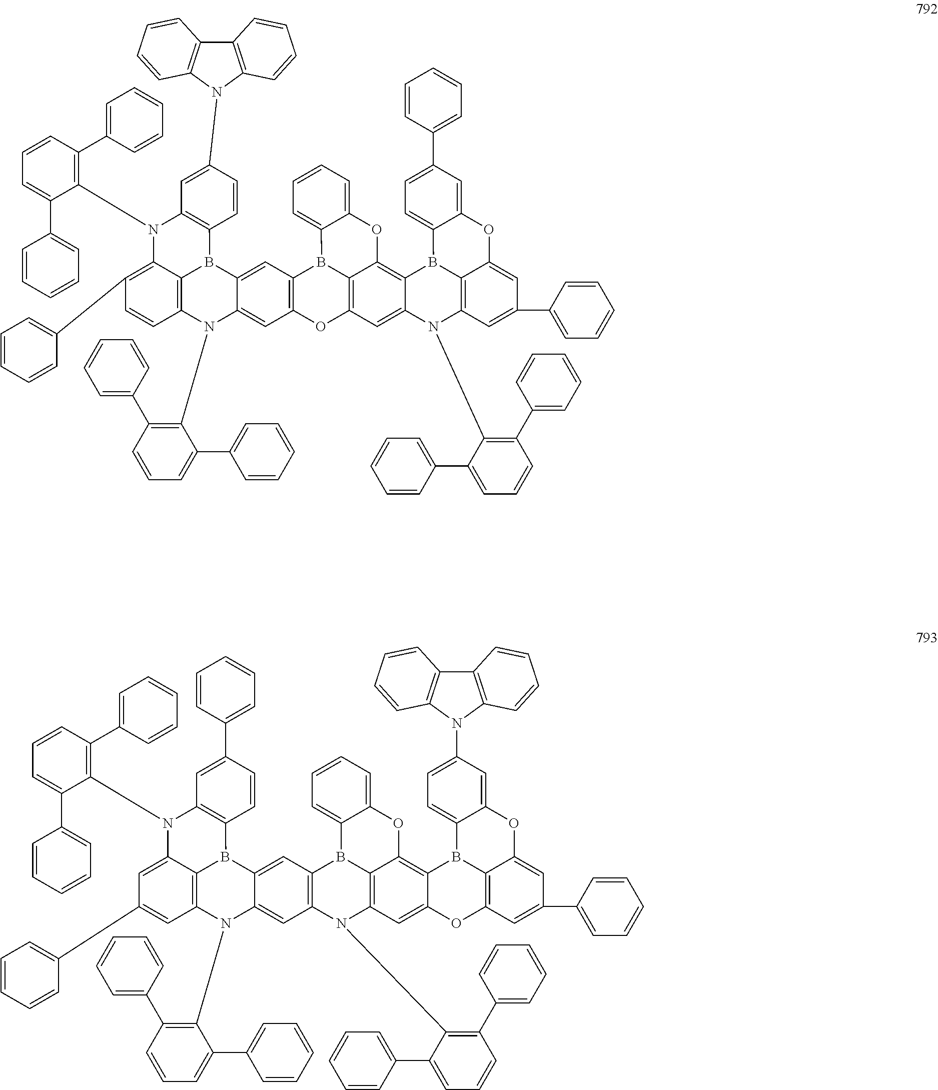 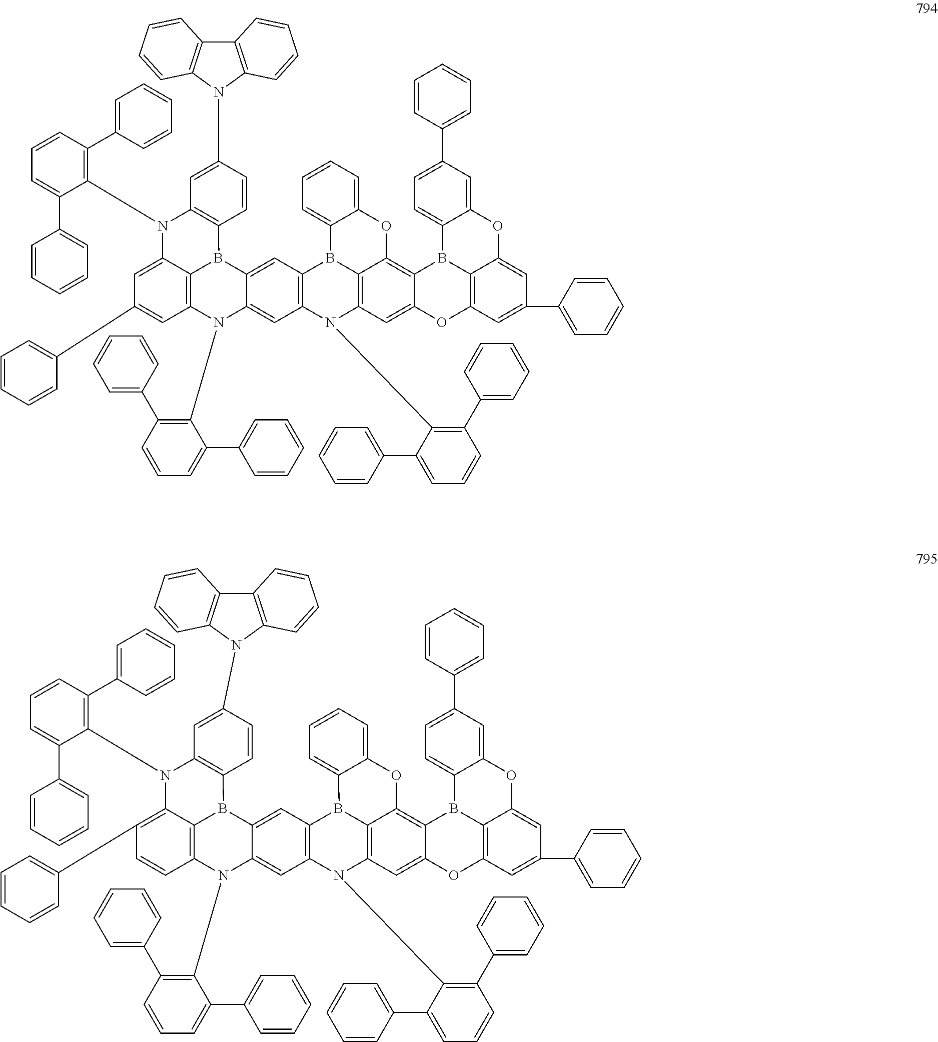 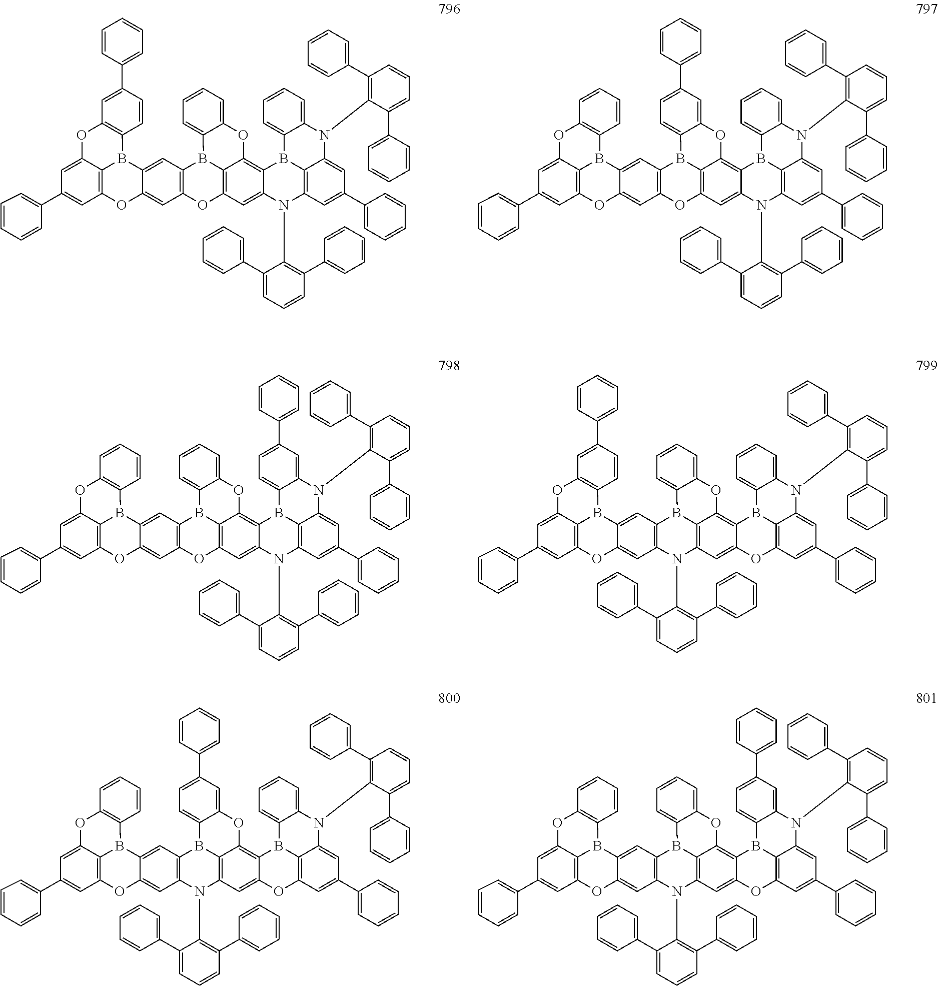 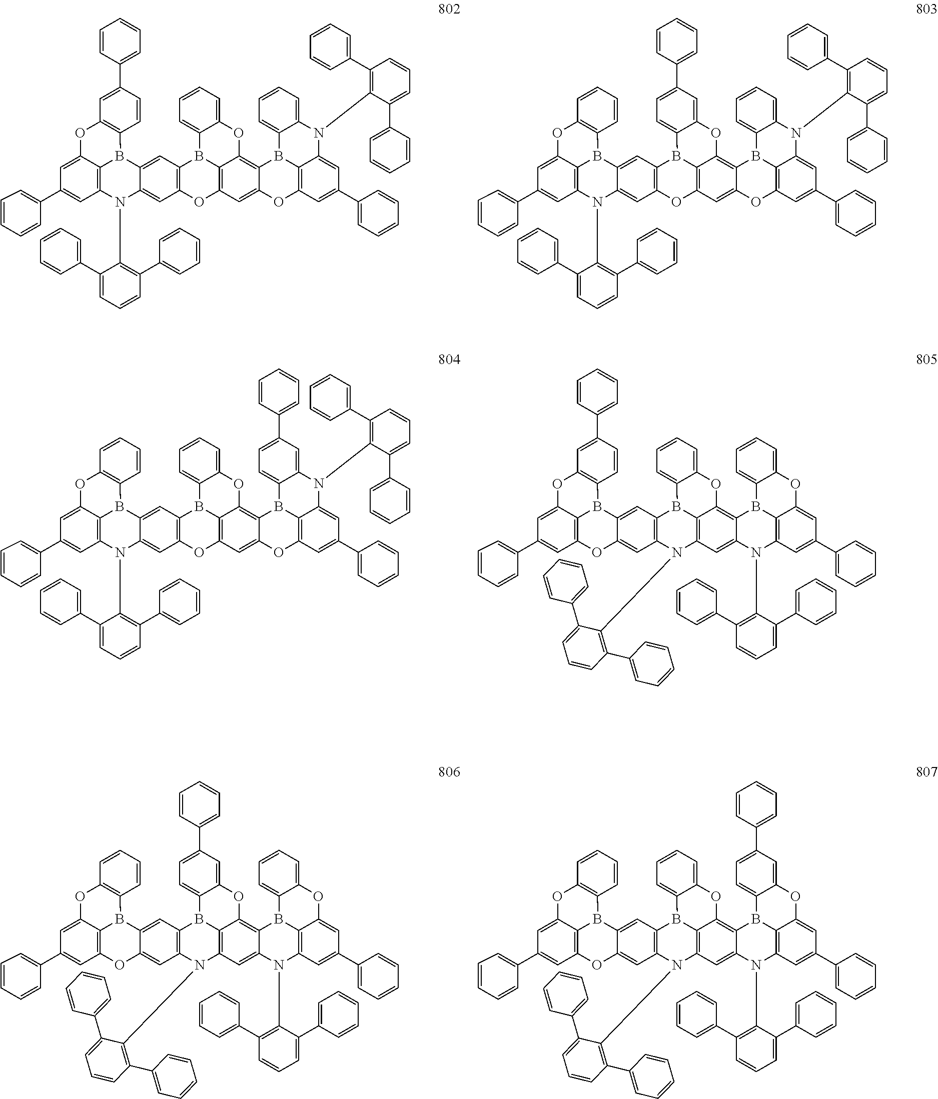 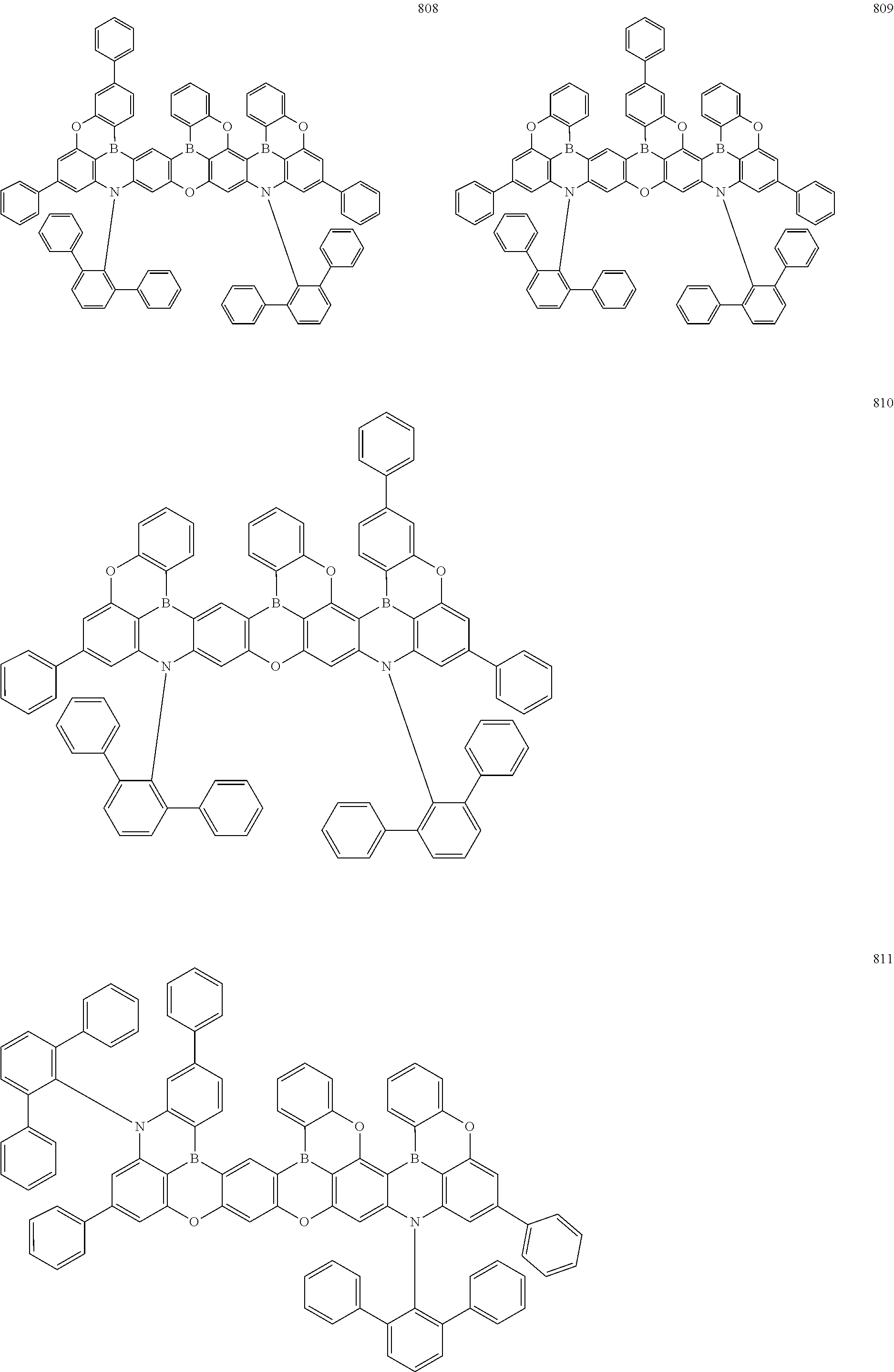 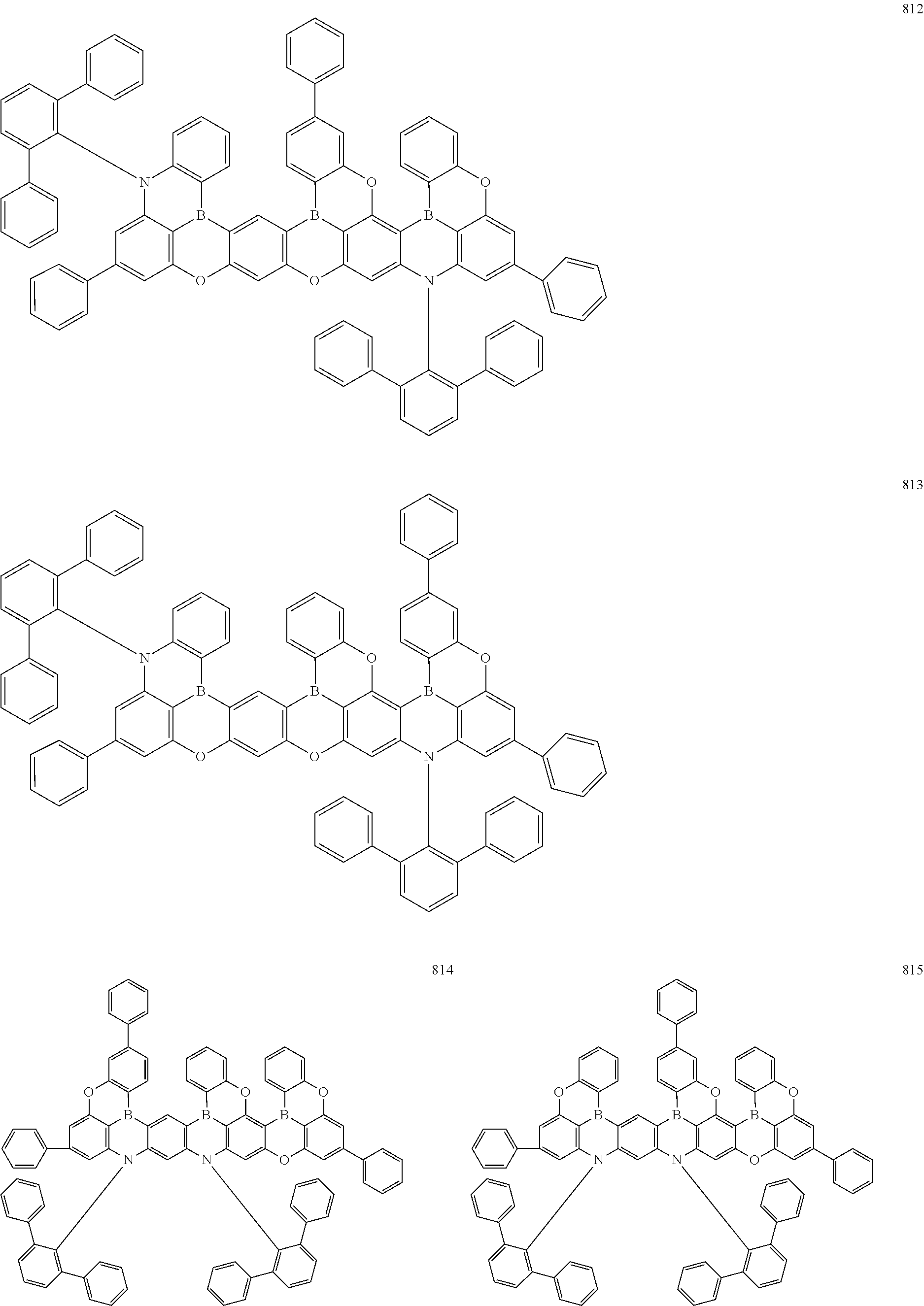 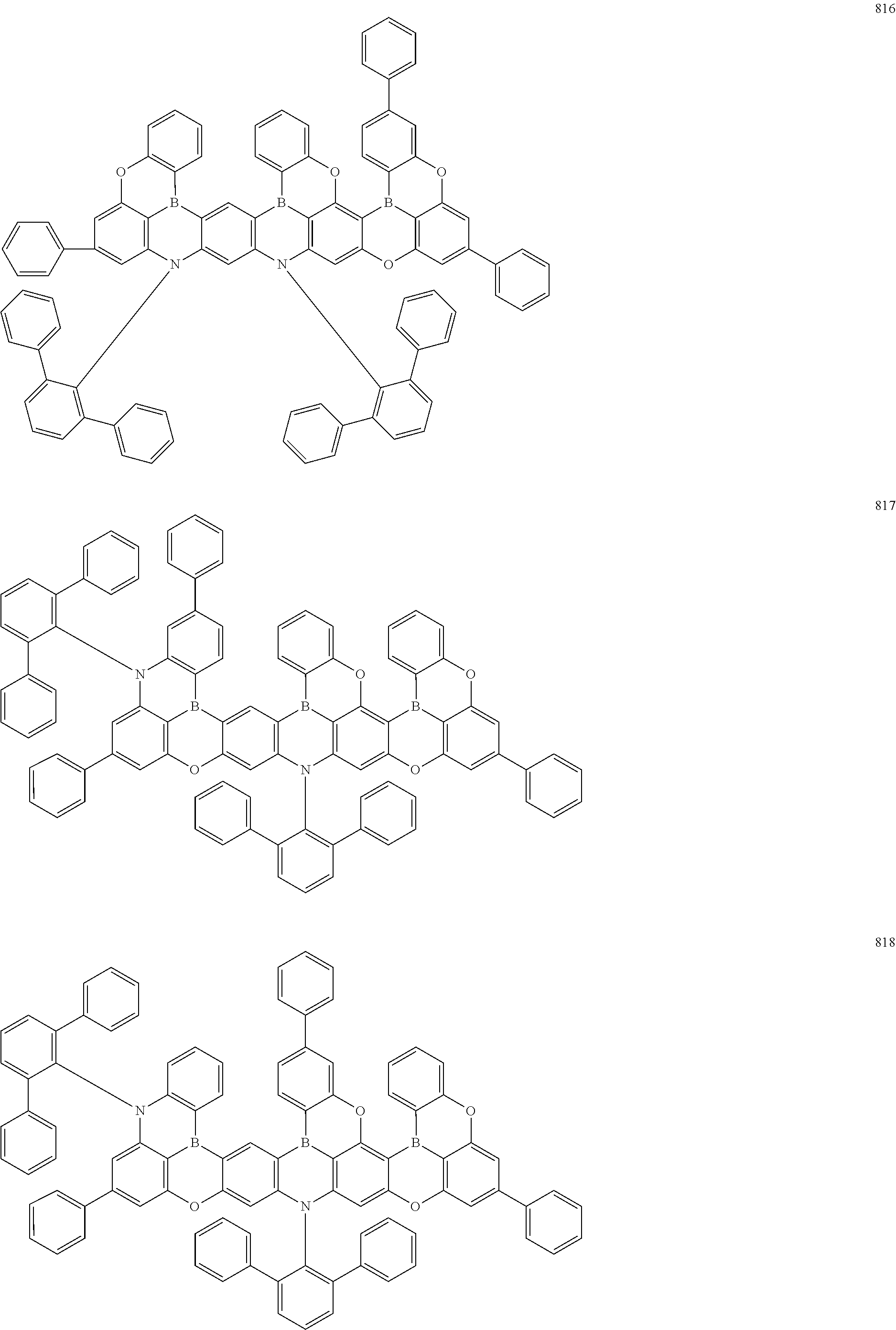 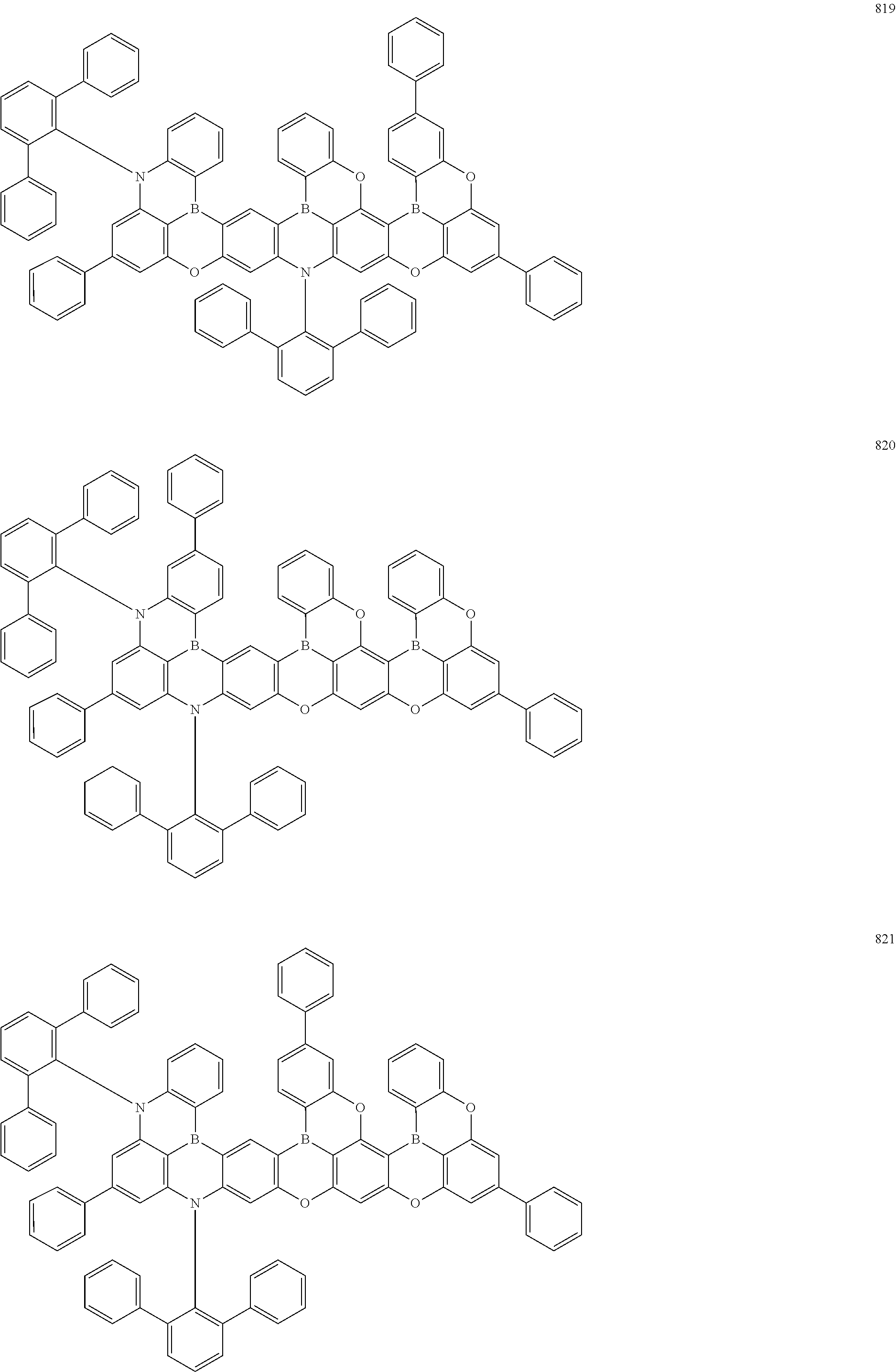 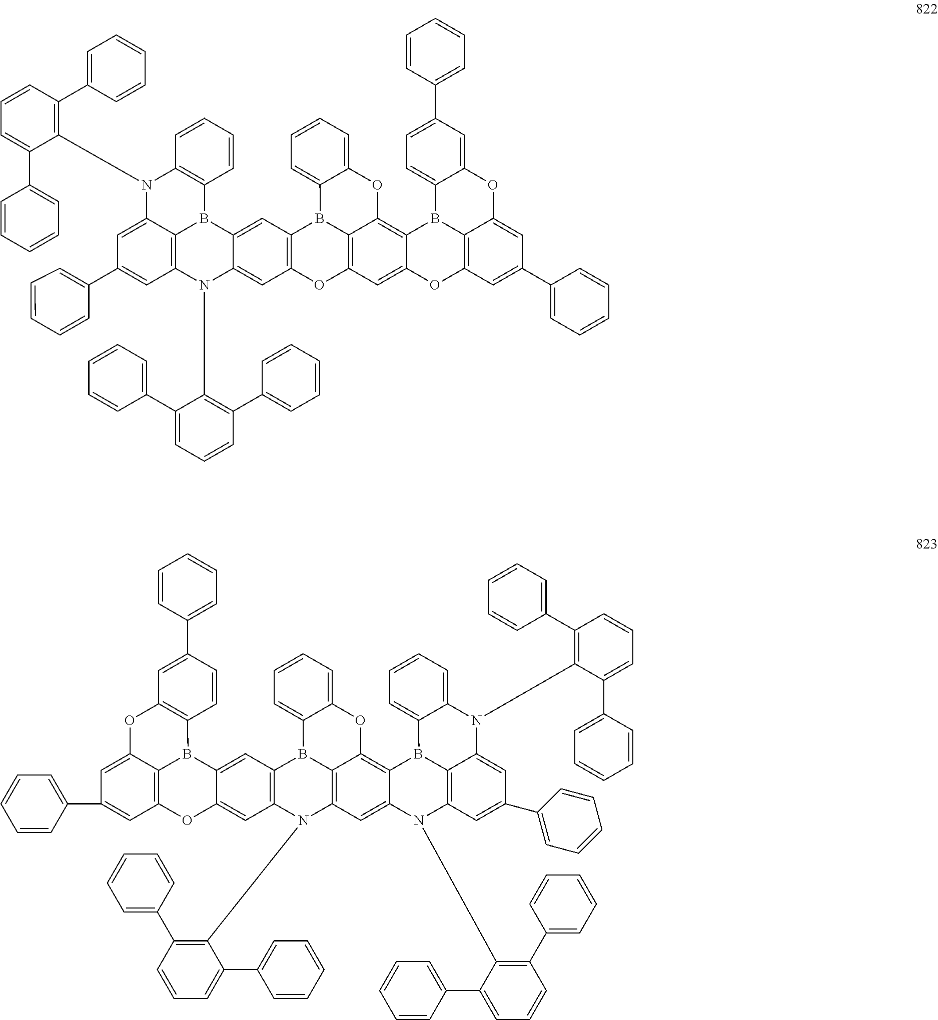 [SMILES: c1ccc(-c2ccc3c(c2)Oc2cc(-c4ccccc4)cc4c2B3c2c(cc3c5c2Oc2ccccc2B5c2cc5c(cc2O3)N(c2c(-c3ccccc3)cccc2-c2ccccc2)c2cc(-c3ccccc3)cc3c2B5c2ccccc2N3c2c(-c3ccccc3)cccc2-c2ccccc2)O4)cc1 ; c1ccc(-c2ccc3c(c2)Oc2cc(-c4ccccc4)cc4c2B3c2cc3c(cc2O4)N(c2c(-c4ccccc4)cccc2-c2ccccc2)c2cc4c(c5c2B3c2ccccc2O5)B2c3ccccc3N(c3c(-c5ccccc5)cccc3-c3ccccc3)c3cc(-c5ccccc5)cc(c32)N4c2c(-c3ccccc3)cccc2-c2ccccc2)cc1] 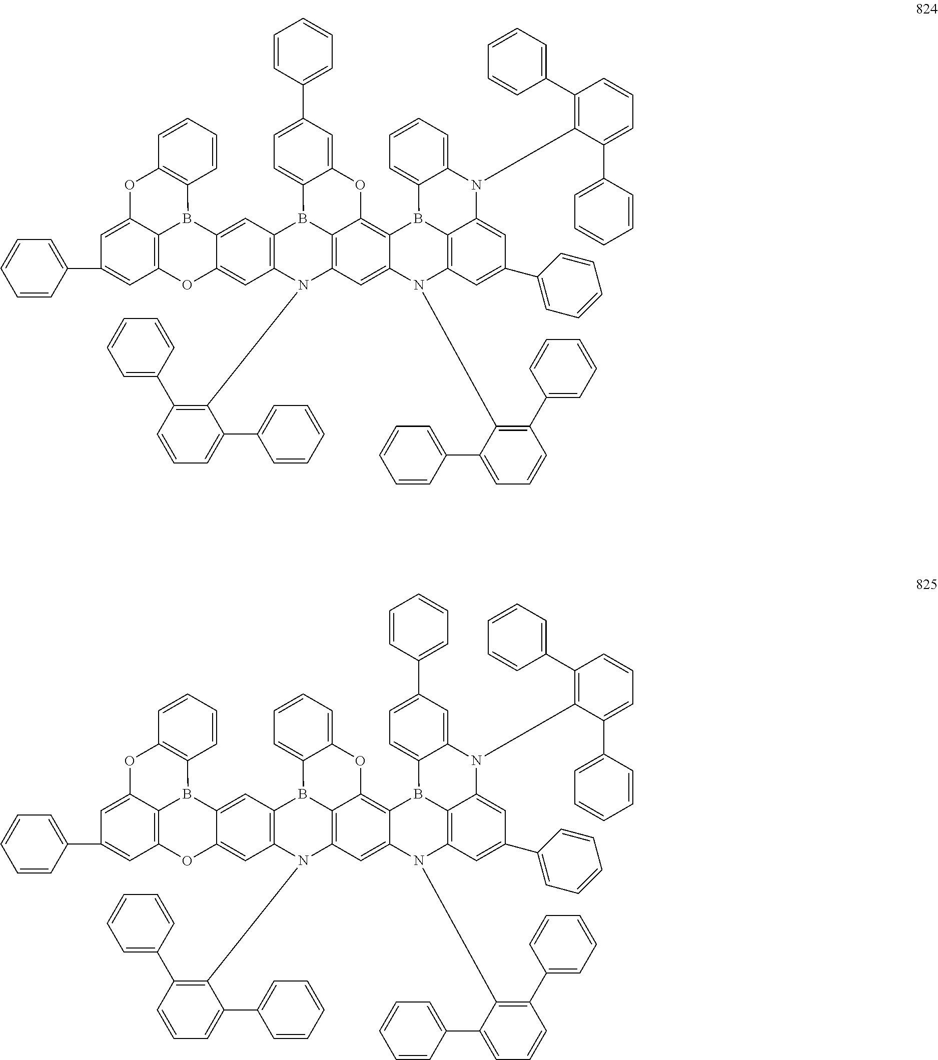 [SMILES: c1ccc(-c2ccc3c(c2)Oc2c4c(cc5c2B2c6ccccc6N(c6c(-c7ccccc7)cccc6-c6ccccc6)c6cc(-c7ccccc7)cc(c62)N5c2c(-c5ccccc5)cccc2-c2ccccc2)N(c2c(-c5ccccc5)cccc2-c2ccccc2)c2cc5c(cc2B34)B2c3ccccc3Oc3cc(-c4ccccc4)cc(c32)O5)cc1 ; c1ccc(-c2cc3c4c(c2)Oc2cc5c(cc2B4c2ccccc2O3)B2c3ccccc3Oc3c2c(cc2c3B3c4ccc(-c6ccccc6)cc4N(c4c(-c6ccccc6)cccc4-c4ccccc4)c4cc(-c6ccccc6)cc(c43)N2c2c(-c3ccccc3)cccc2-c2ccccc2)N5c2c(-c3ccccc3)cccc2-c2ccccc2)cc1] 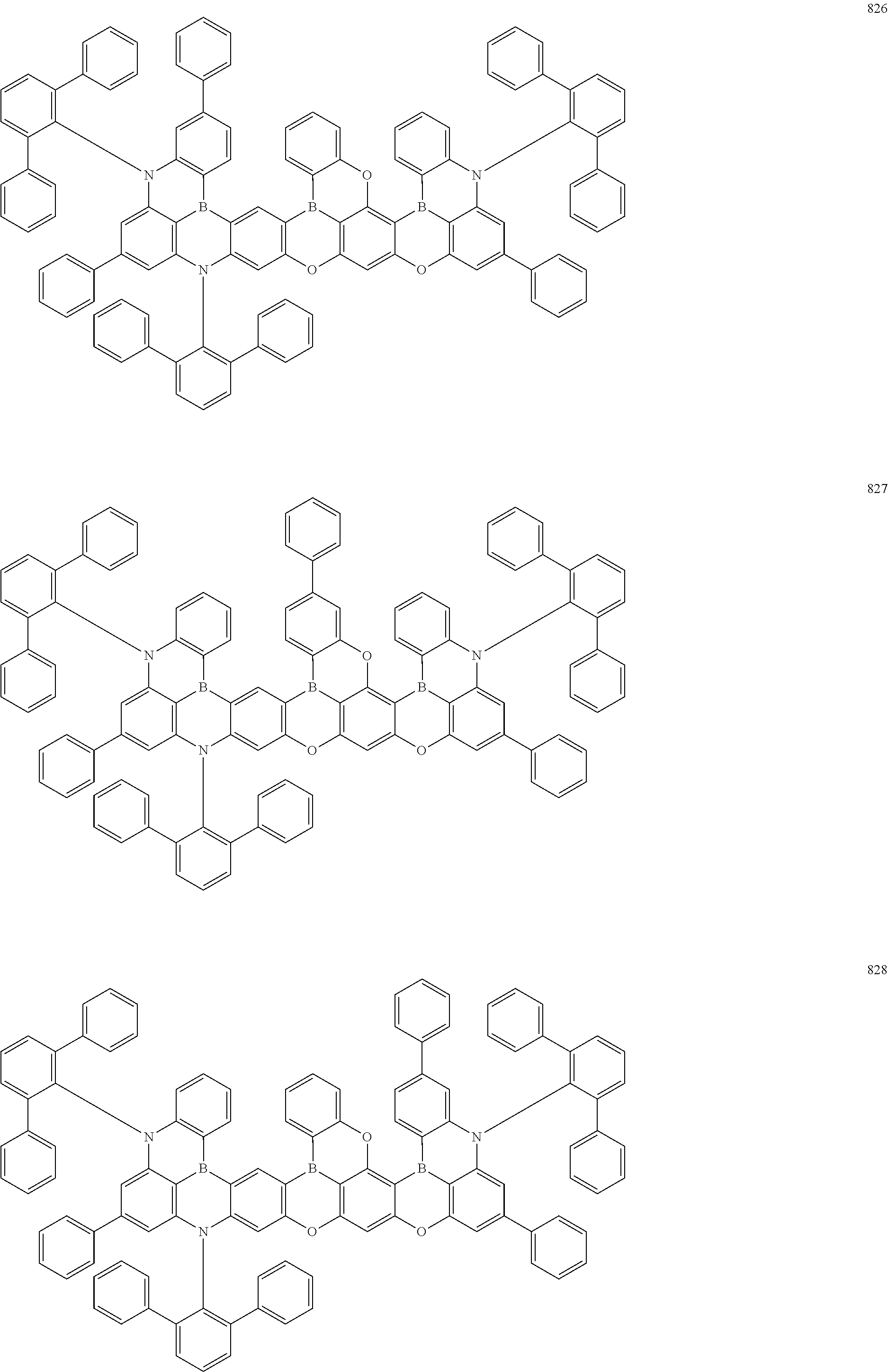 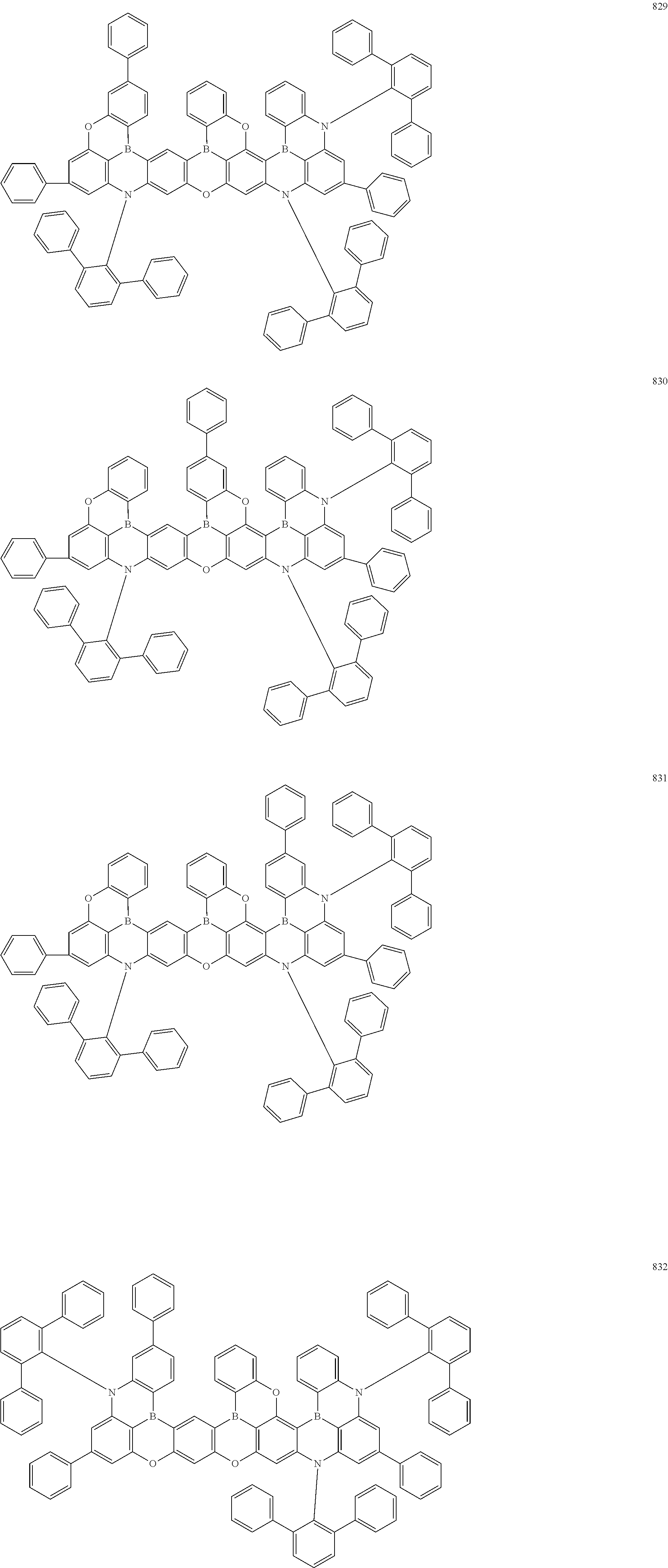 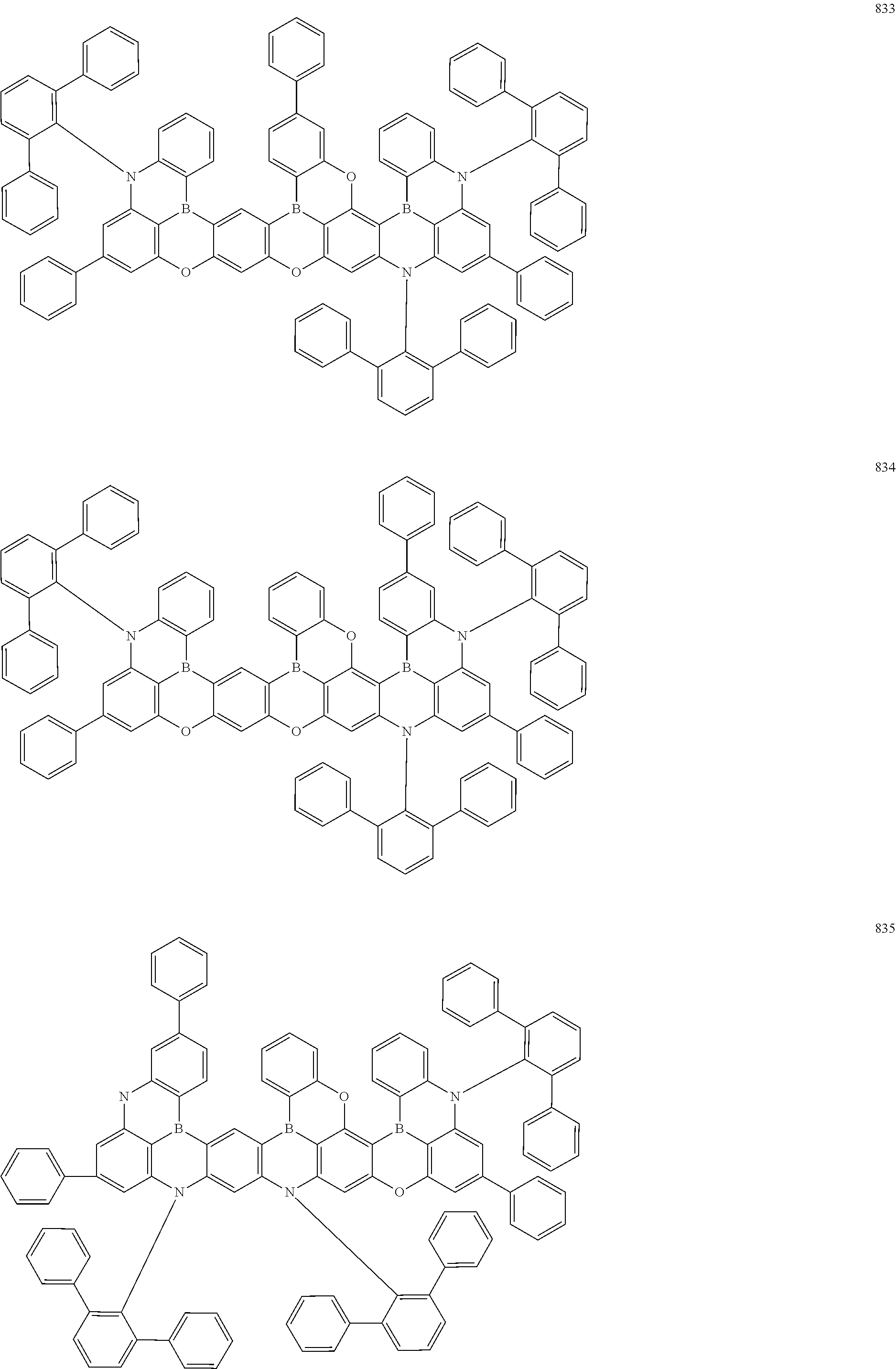 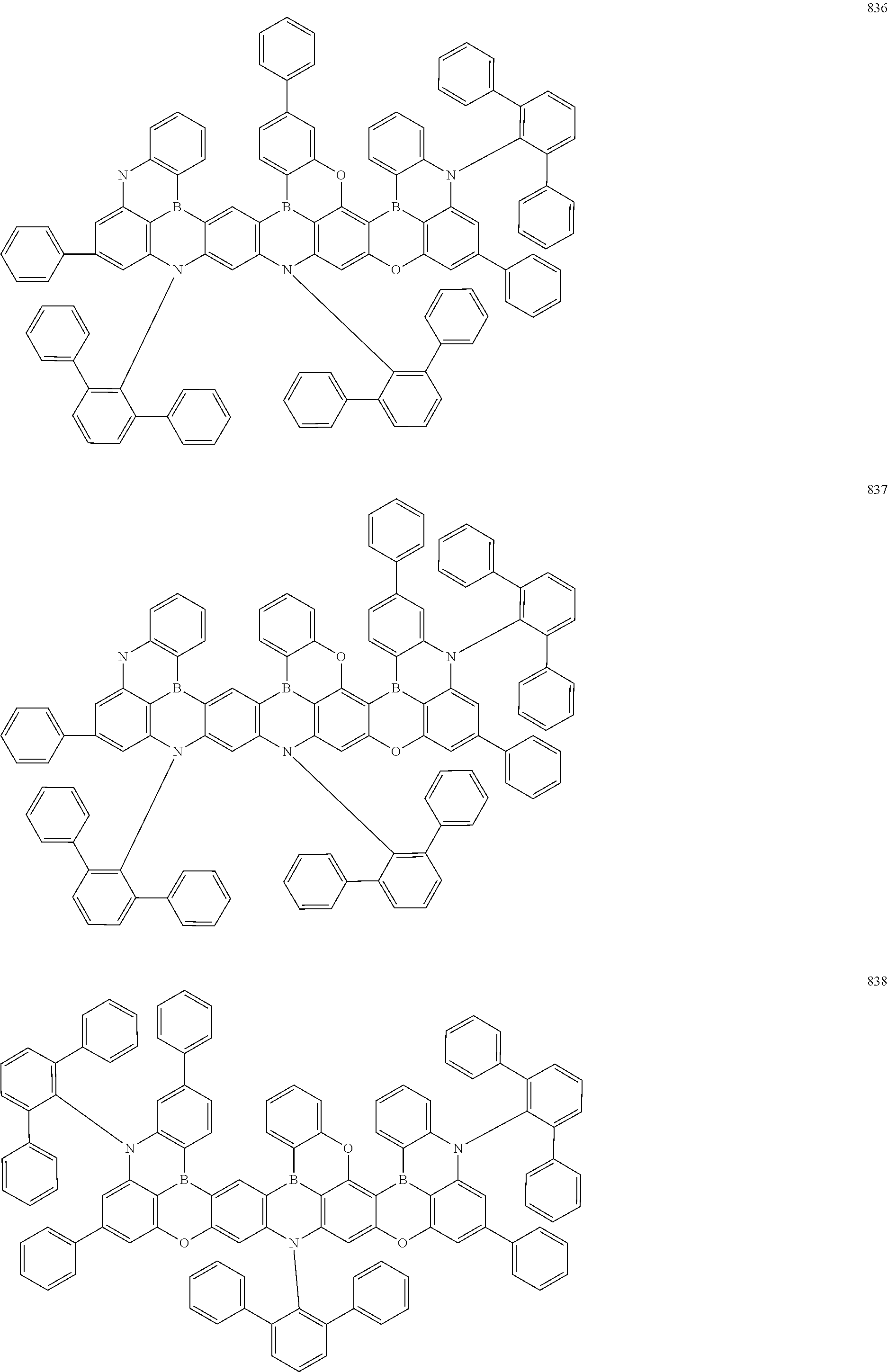 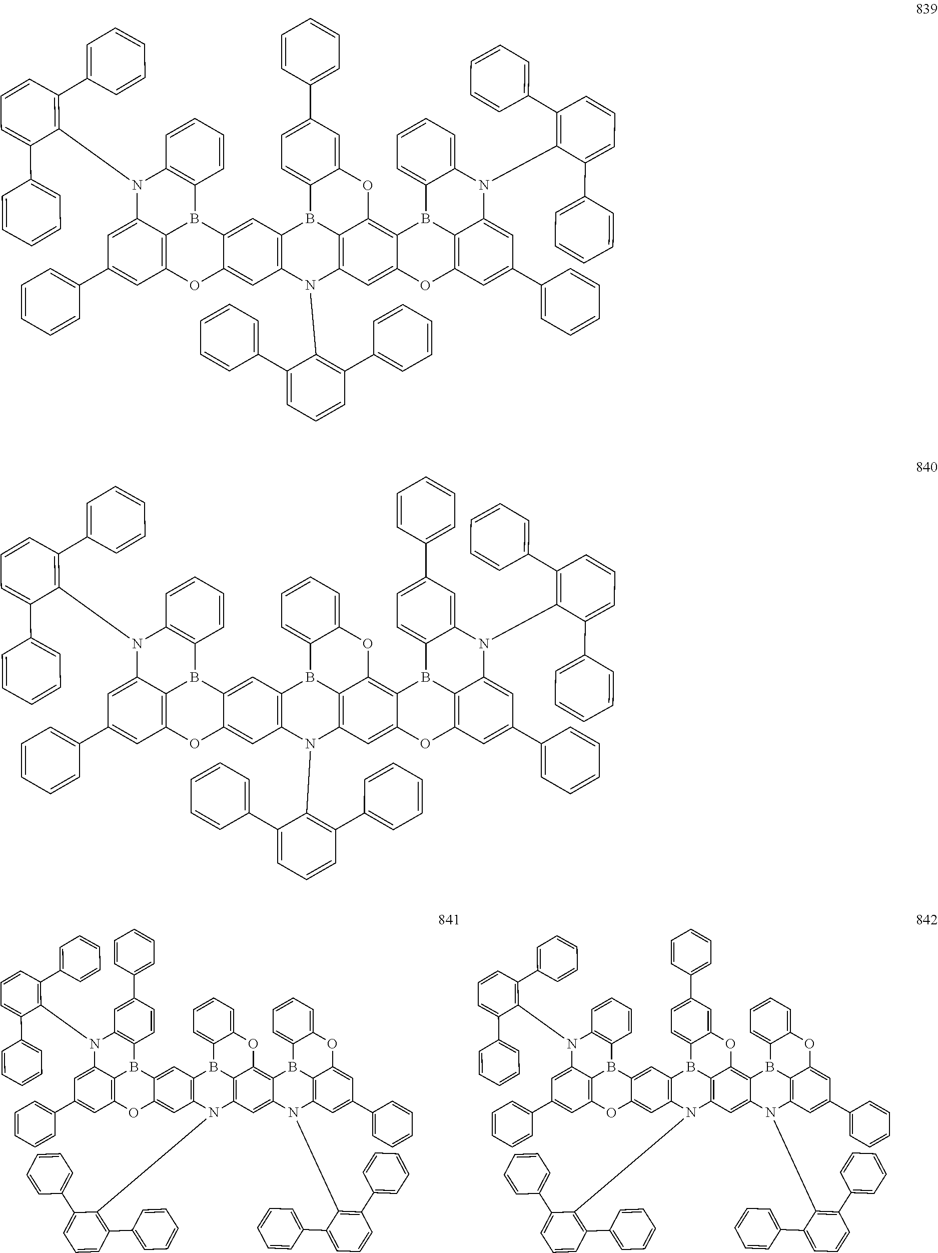 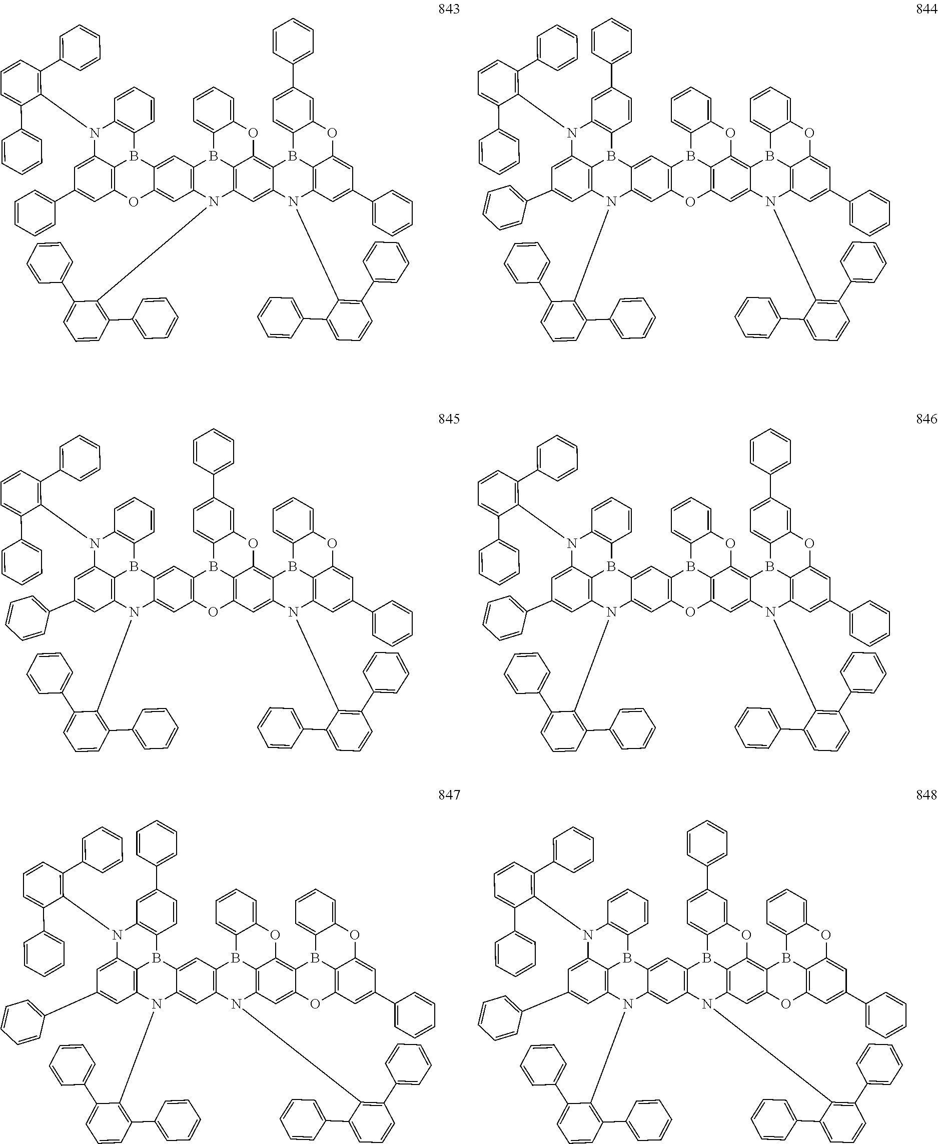 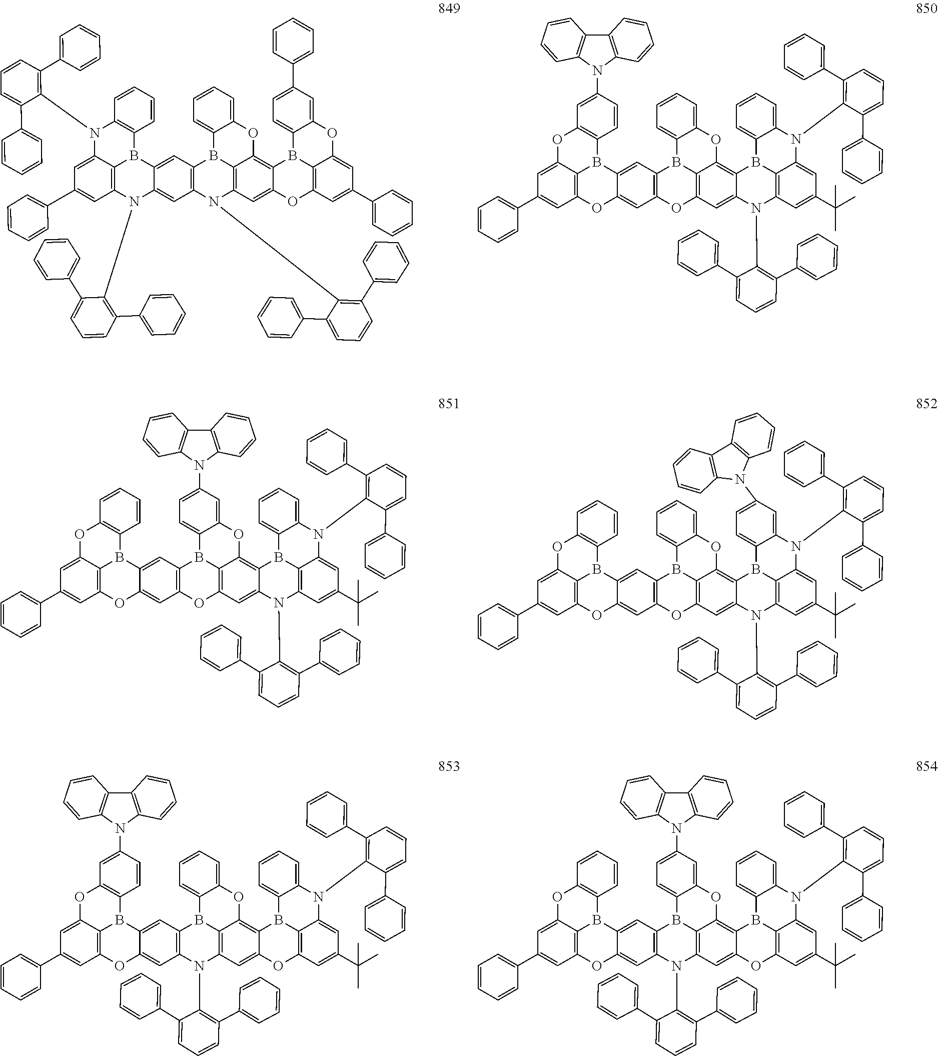 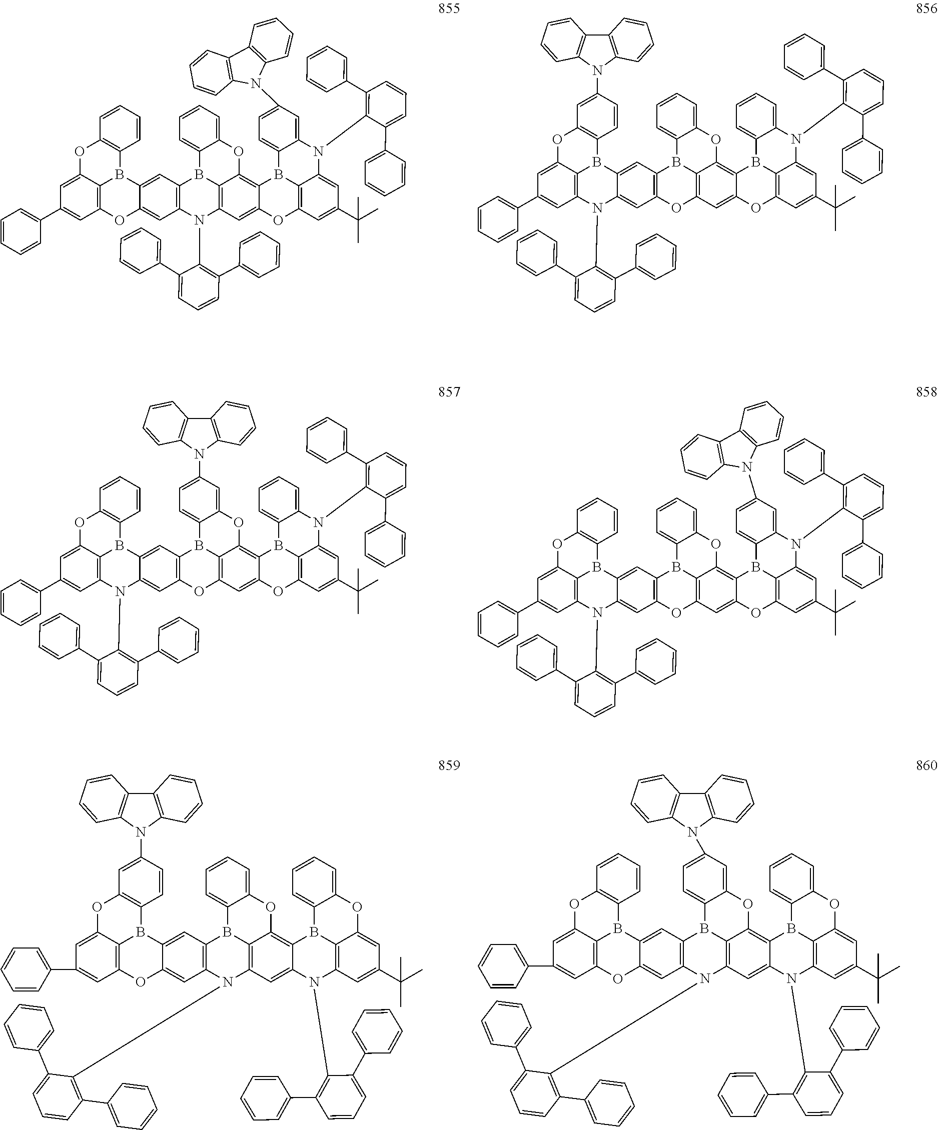 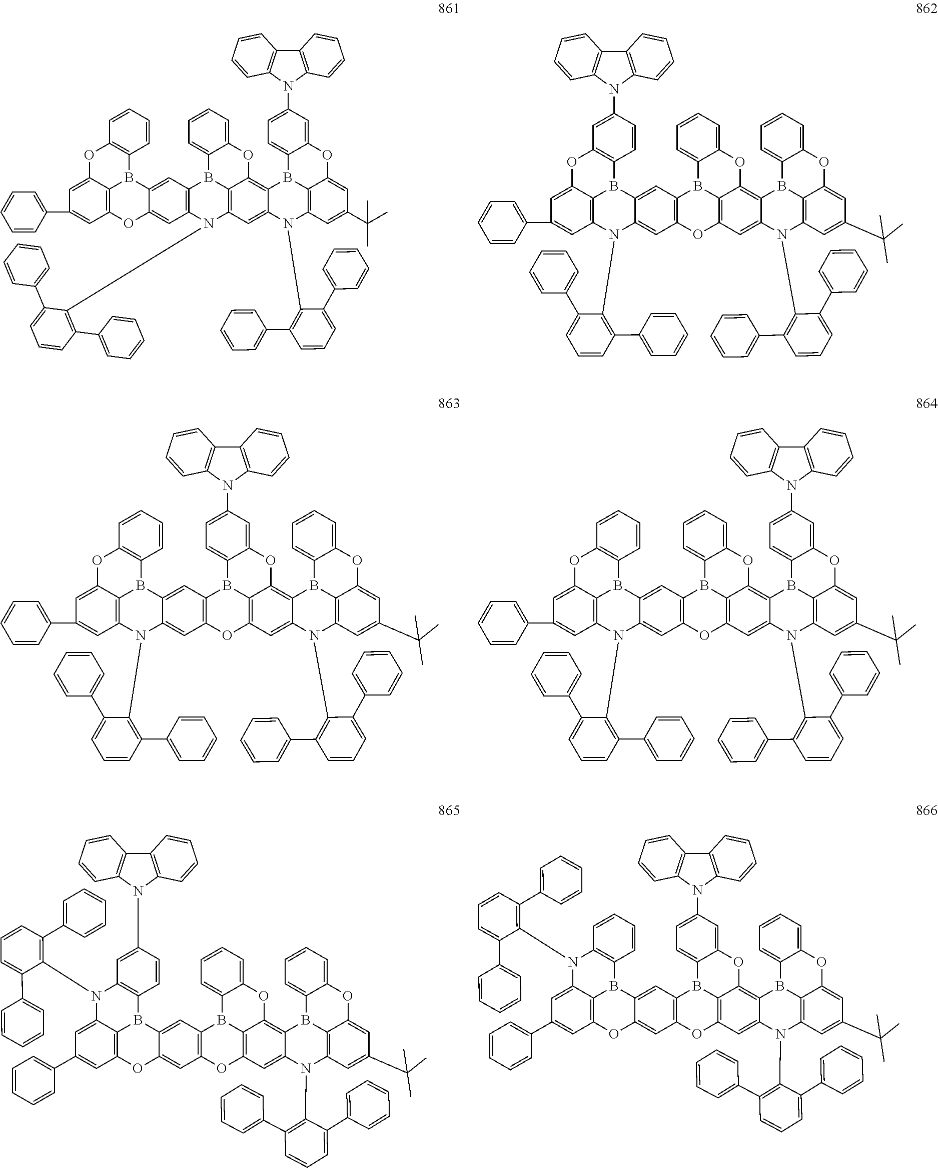 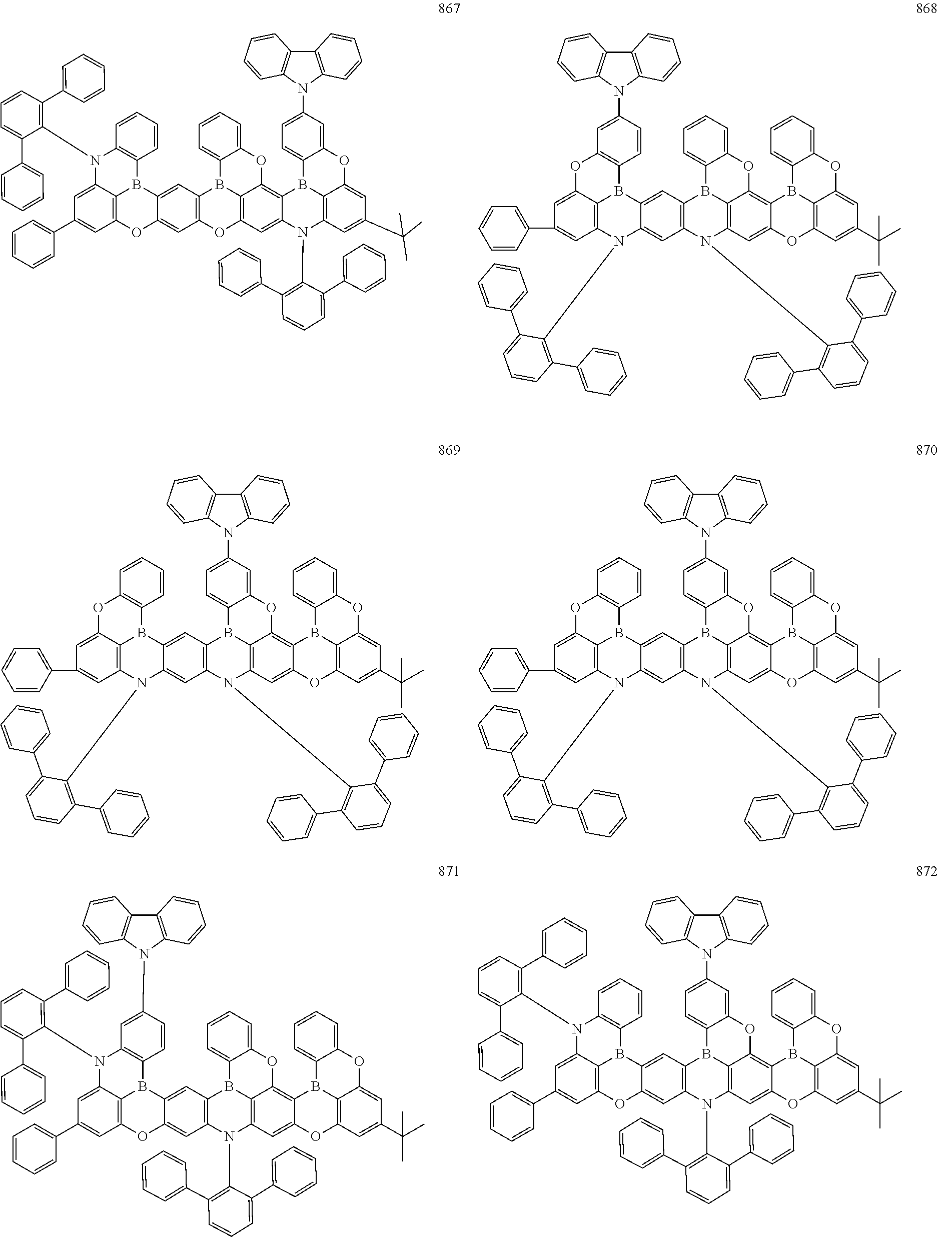 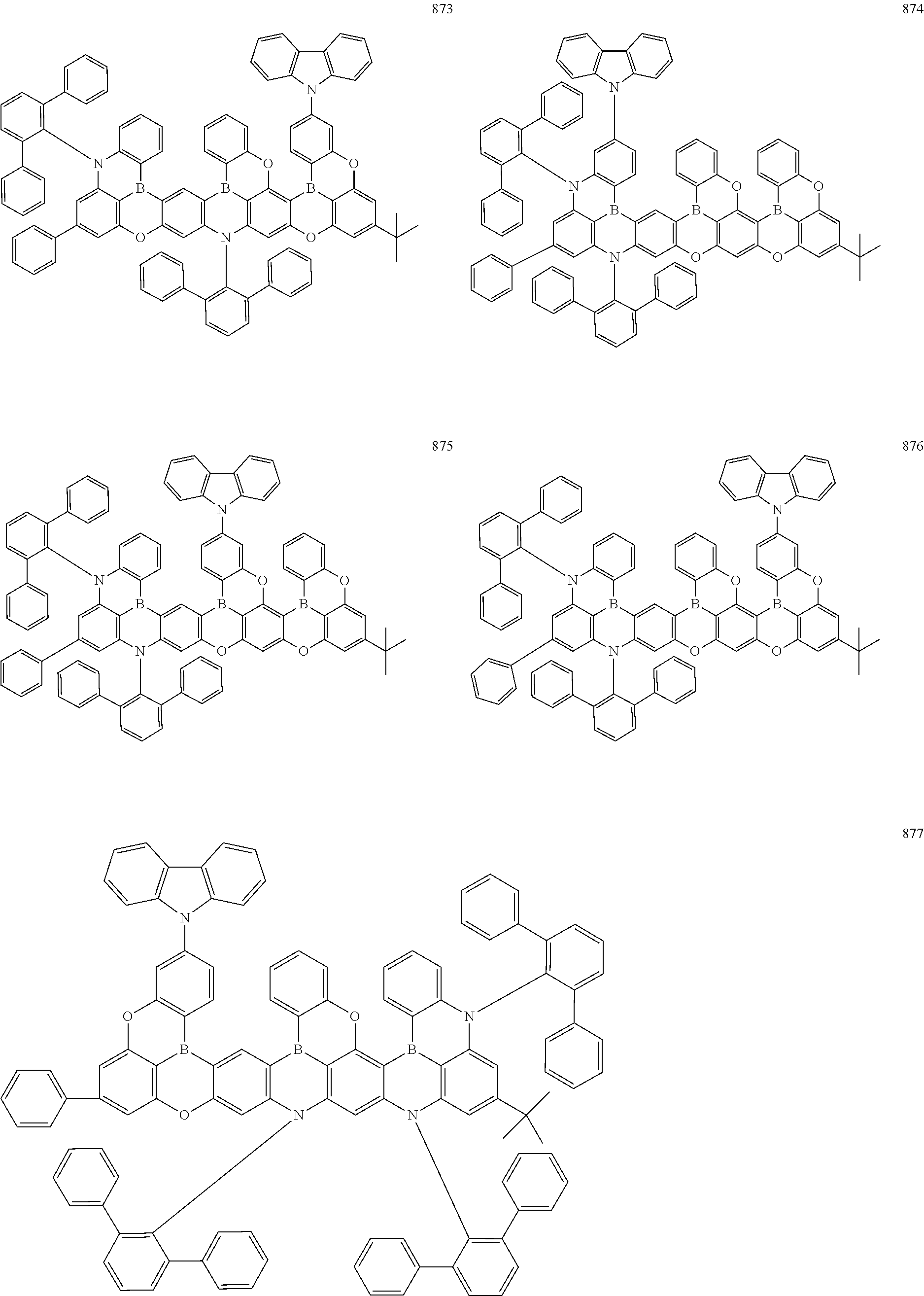 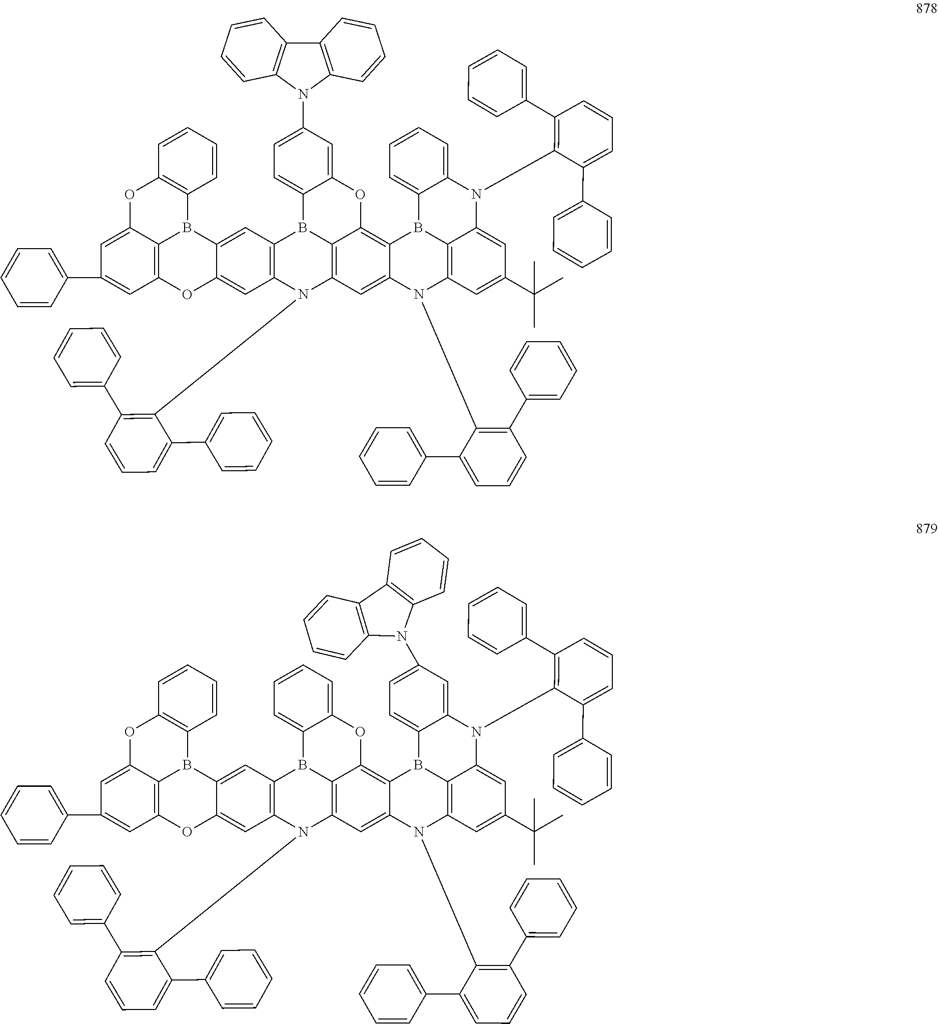 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1N4c1c(-c3ccccc3)cccc1-c1ccccc1)Oc1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccccc1O3] 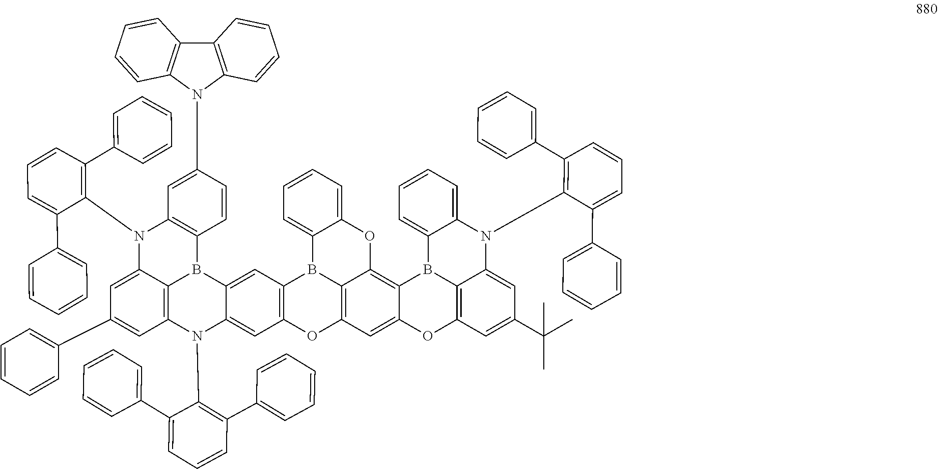 [SMILES: CC(C)(C)c1cc2c3c(c1)N(c1c(-c4ccccc4)cccc1-c1ccccc1)c1ccccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1N3c1c(-c3ccccc3)cccc1-c1ccccc1)O2] 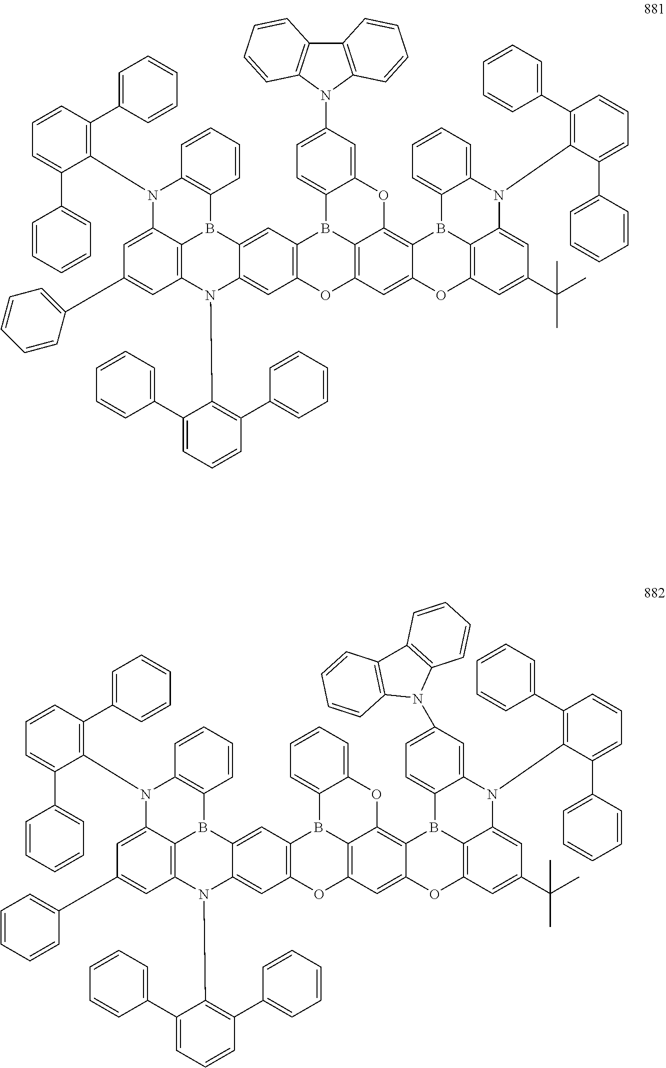 [SMILES: CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1O3)N(c1c(-c3ccccc3)cccc1-c1ccccc1)c1cc(-c3ccccc3)cc3c1B4c1ccccc1N3c1c(-c3ccccc3)cccc1-c1ccccc1)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccccc1N3c1c(-c3ccccc3)cccc1-c1ccccc1)O2] 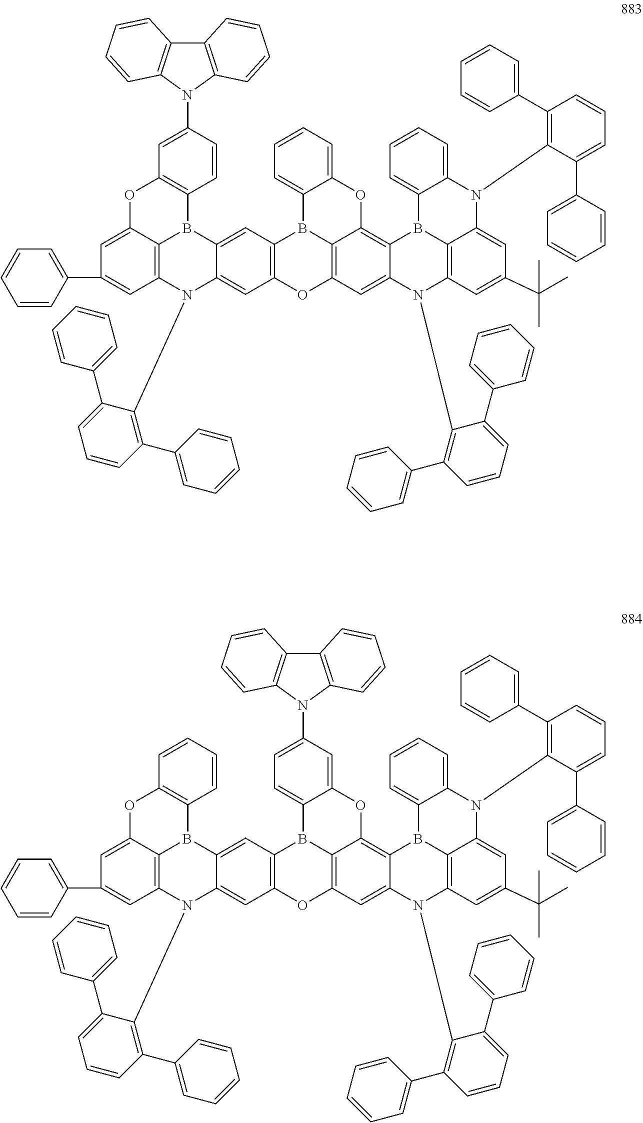 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1O3] 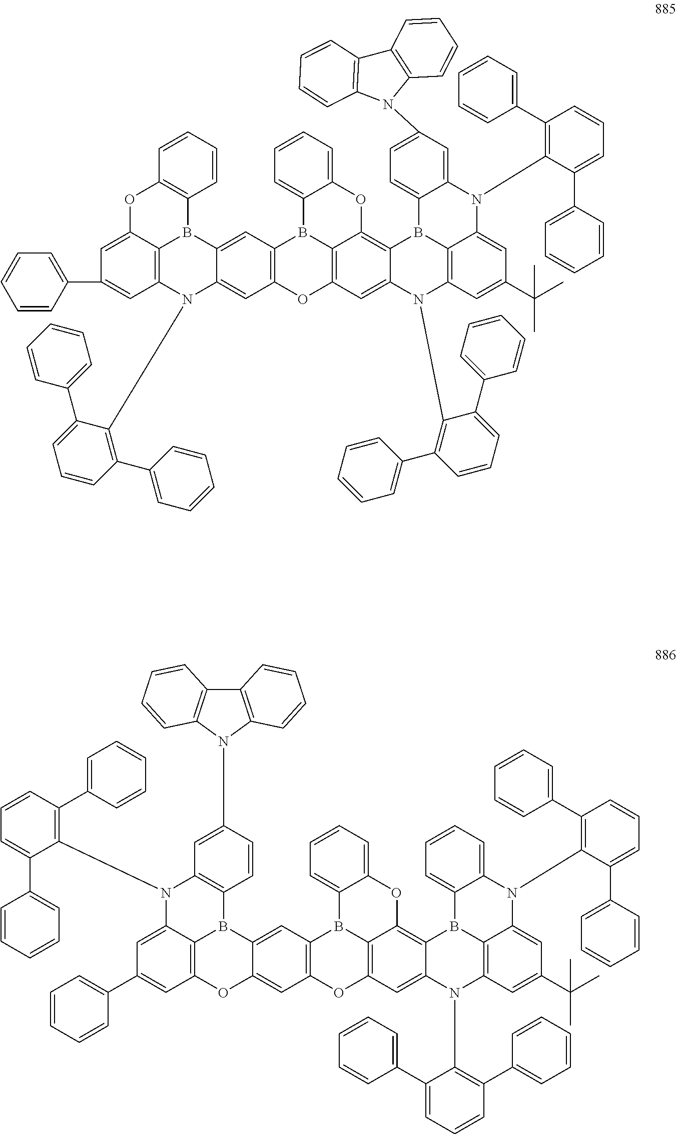 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccccc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1] 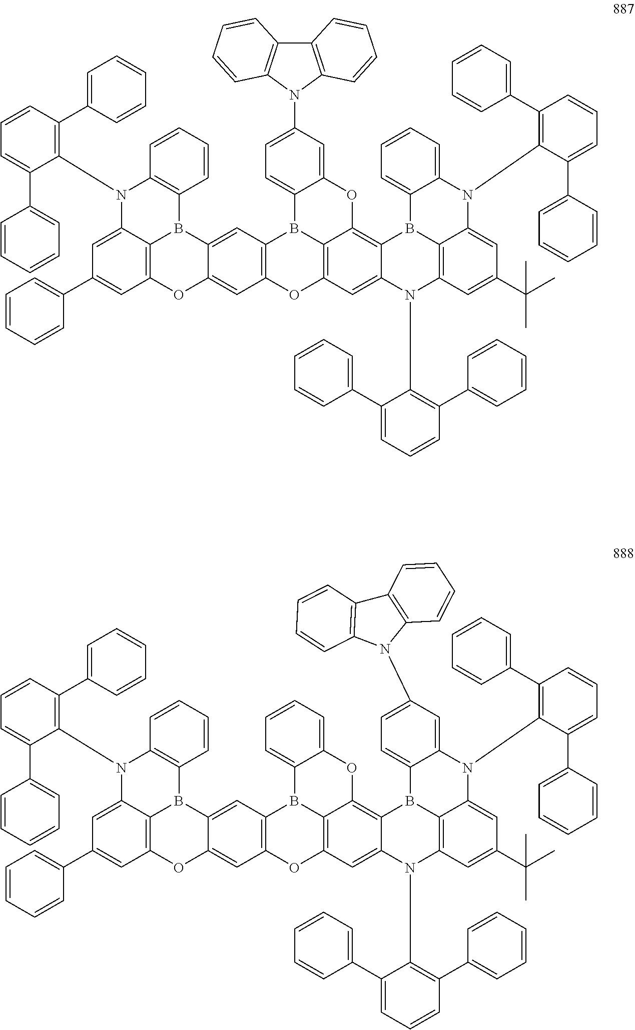 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-n2c3ccccc3c3ccccc32)ccc1B5c1cc2c(cc1O4)Oc1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)Oc1cc(-c3ccccc3)cc3c1B2c1ccccc1N3c1c(-c2ccccc2)cccc1-c1ccccc1] 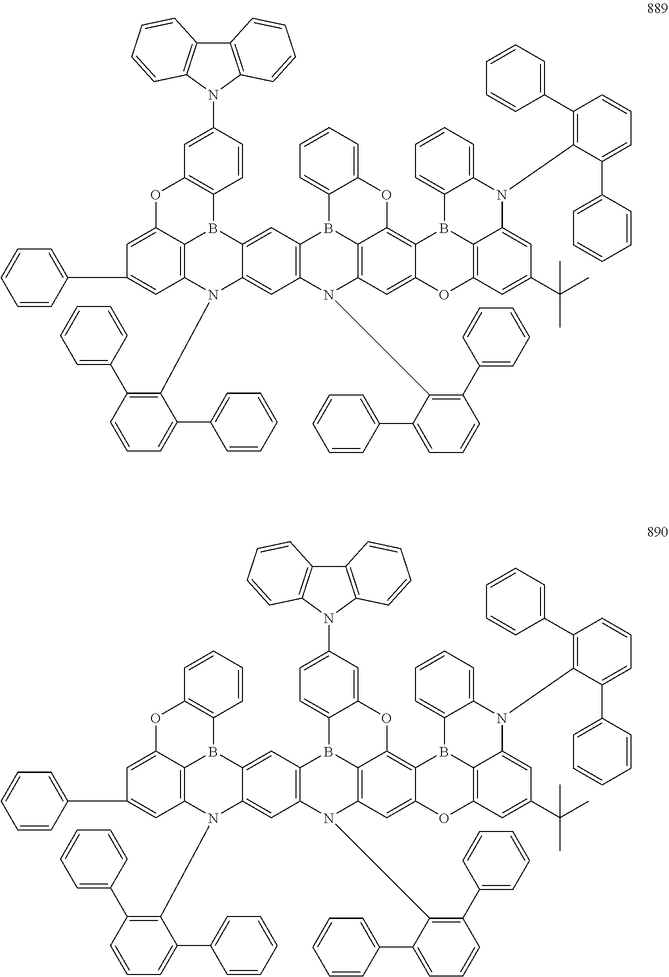 [SMILES: CC(C)(C)c1cc2c3c(c1)N(c1c(-c4ccccc4)cccc1-c1ccccc1)c1ccccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccccc1O3)O2] 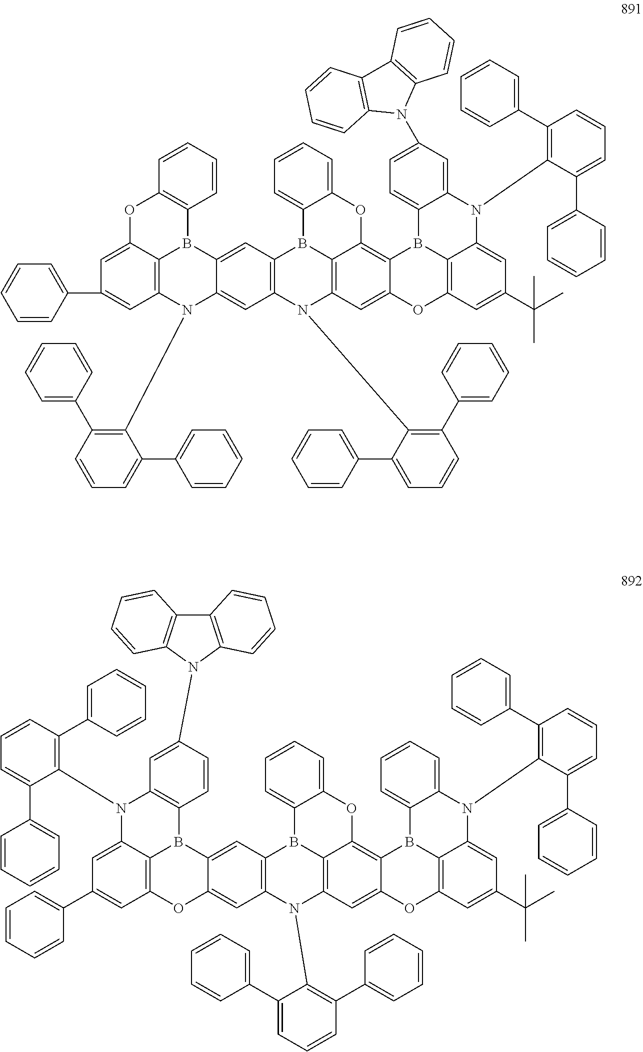 [SMILES: CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccccc1O3)O2 ; CC(C)(C)c1cc2c3c(c1)N(c1c(-c4ccccc4)cccc1-c1ccccc1)c1ccccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1N3c1c(-c3ccccc3)cccc1-c1ccccc1)O2] 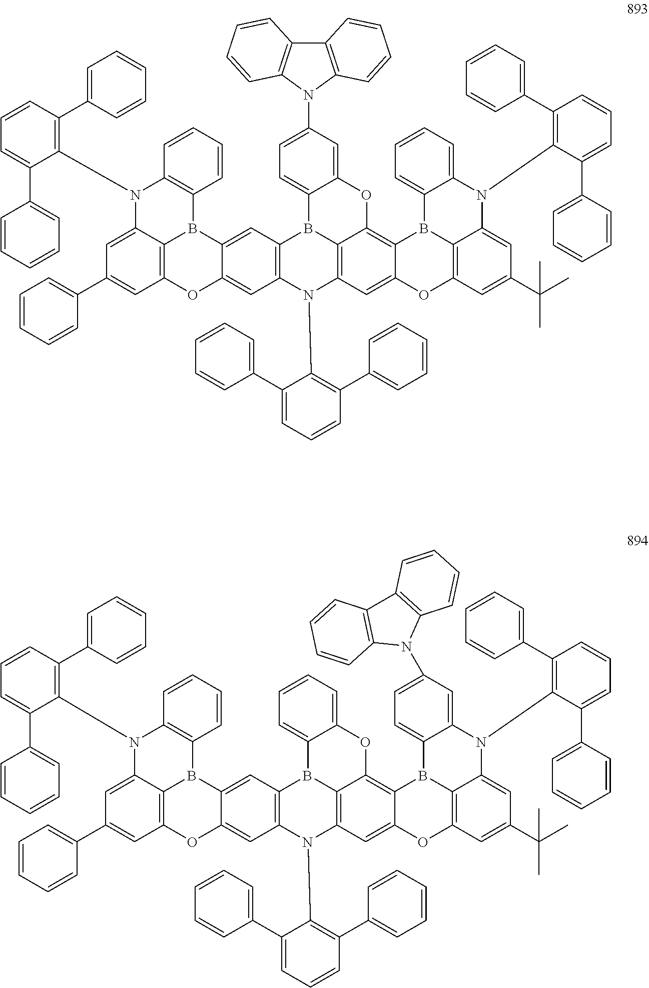 [SMILES: CC(C)(C)c1cc2c3c(c1)N(c1c(-c4ccccc4)cccc1-c1ccccc1)c1ccccc1B3c1c(cc3c4c1Oc1cc(-n5c6ccccc6c6ccccc65)ccc1B4c1cc4c(cc1N3c1c(-c3ccccc3)cccc1-c1ccccc1)Oc1cc(-c3ccccc3)cc3c1B4c1ccccc1N3c1c(-c3ccccc3)cccc1-c1ccccc1)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccccc1N3c1c(-c3ccccc3)cccc1-c1ccccc1)O2] 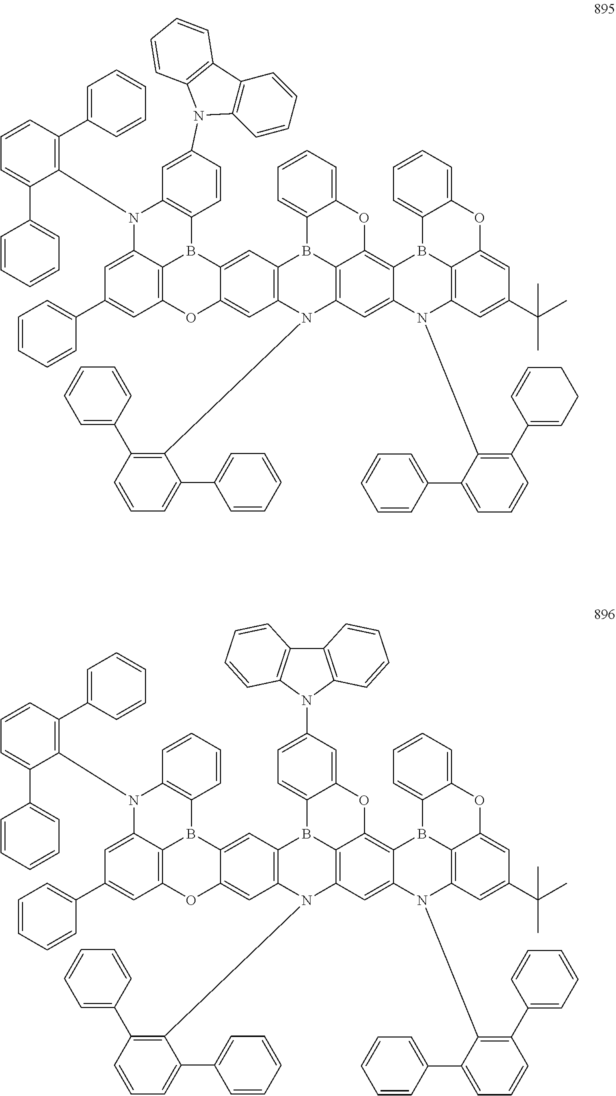 [SMILES: CC(C)(C)c1cc2c3c(c1)N(c1c(C4=CCCC=C4)cccc1-c1ccccc1)c1cc4c5c(c1B3c1ccccc1O2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1N4c1c(-c3ccccc3)cccc1-c1ccccc1)Oc1cc(-c3ccccc3)cc3c1B2c1ccccc1N3c1c(-c2ccccc2)cccc1-c1ccccc1] 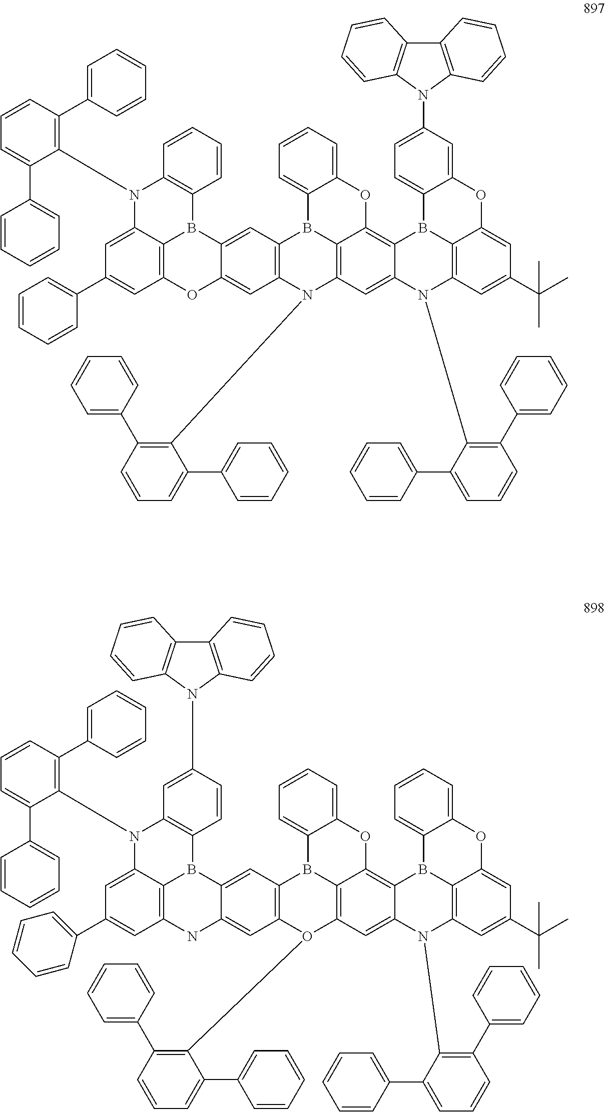 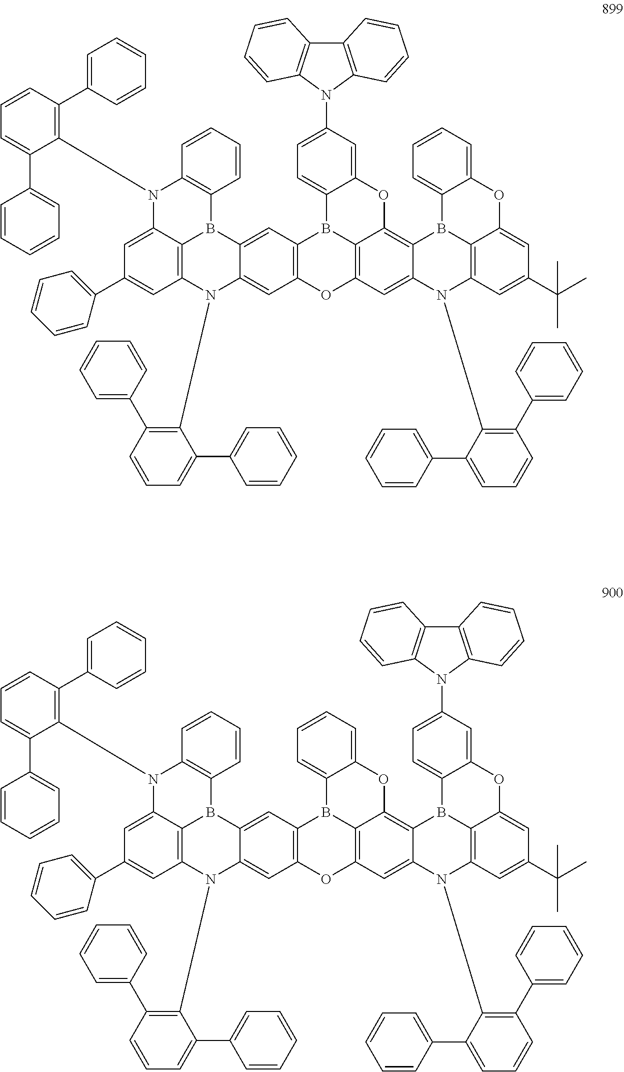 [SMILES: CC(C)(C)c1cc2c3c(c1)N(c1c(-c4ccccc4)cccc1-c1ccccc1)c1cc4c5c(c1B3c1ccccc1O2)Oc1cc(-n2c3ccccc3c3ccccc32)ccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1] 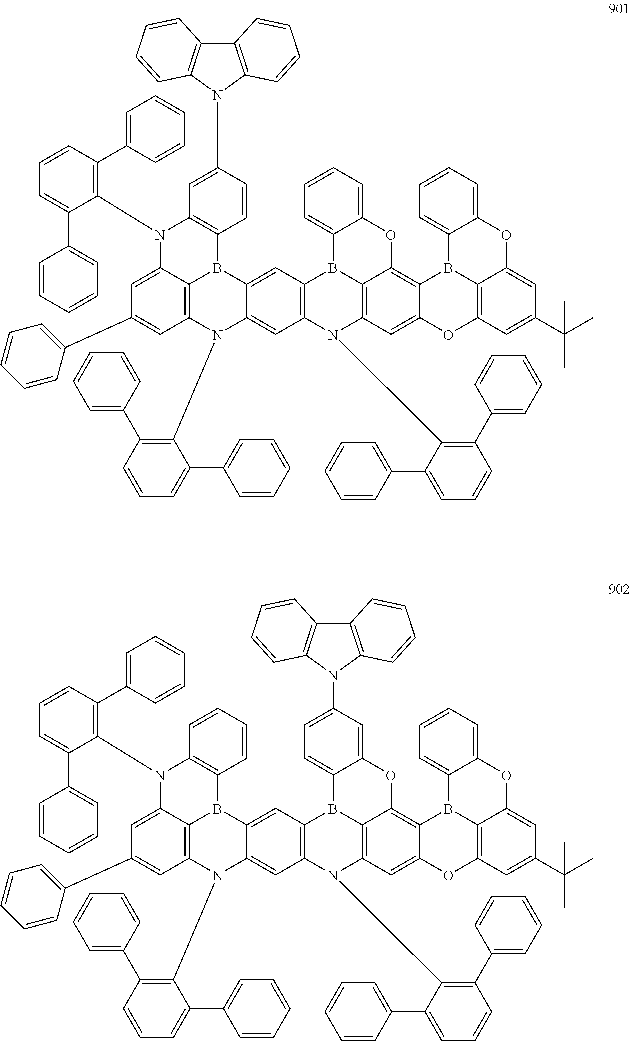 [SMILES: CC(C)(C)c1cc2c3c(c1)Oc1cc4c5c(c1B3c1ccccc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccccc1O2)Oc1cc(-n2c3ccccc3c3ccccc32)ccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccccc1N3c1c(-c2ccccc2)cccc1-c1ccccc1] 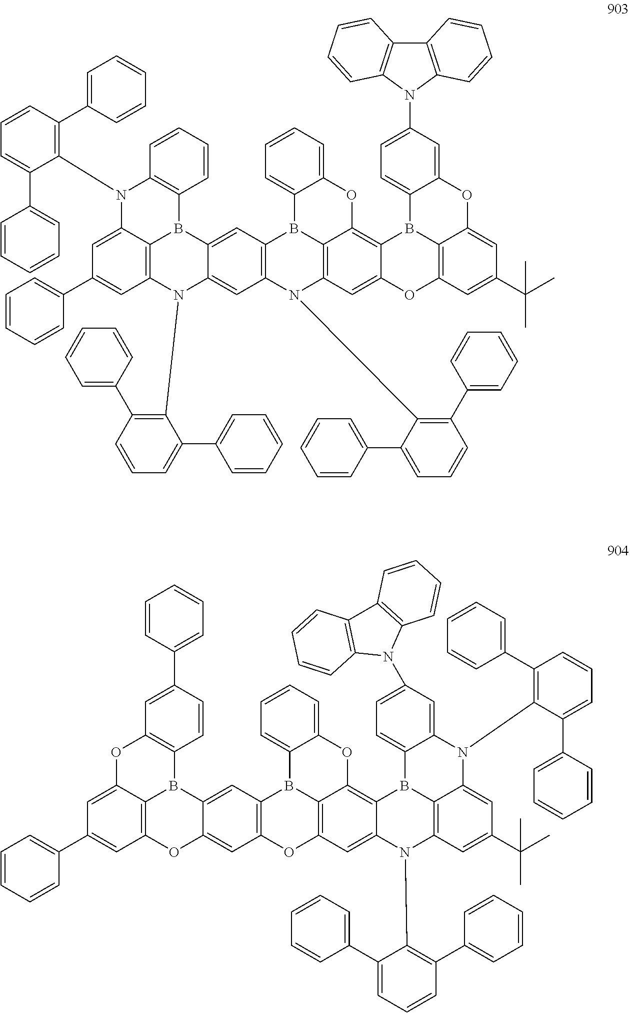 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccccc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)Oc1cc(-c3ccccc3)cc3c1B2c1ccc(-c2ccccc2)cc1O3] 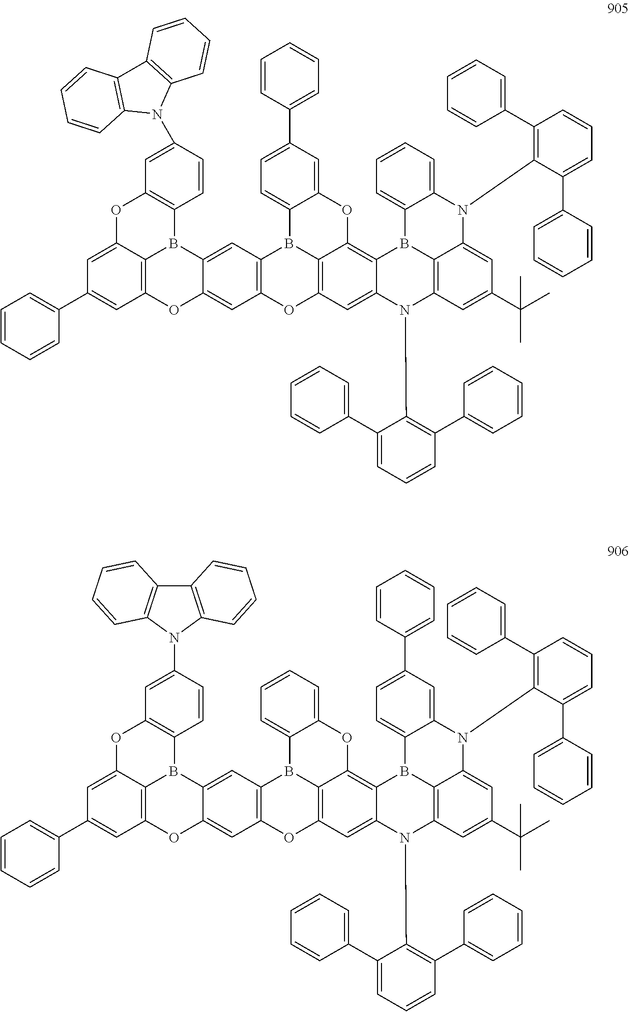 [SMILES: CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1cc2c(cc1O4)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1O3] 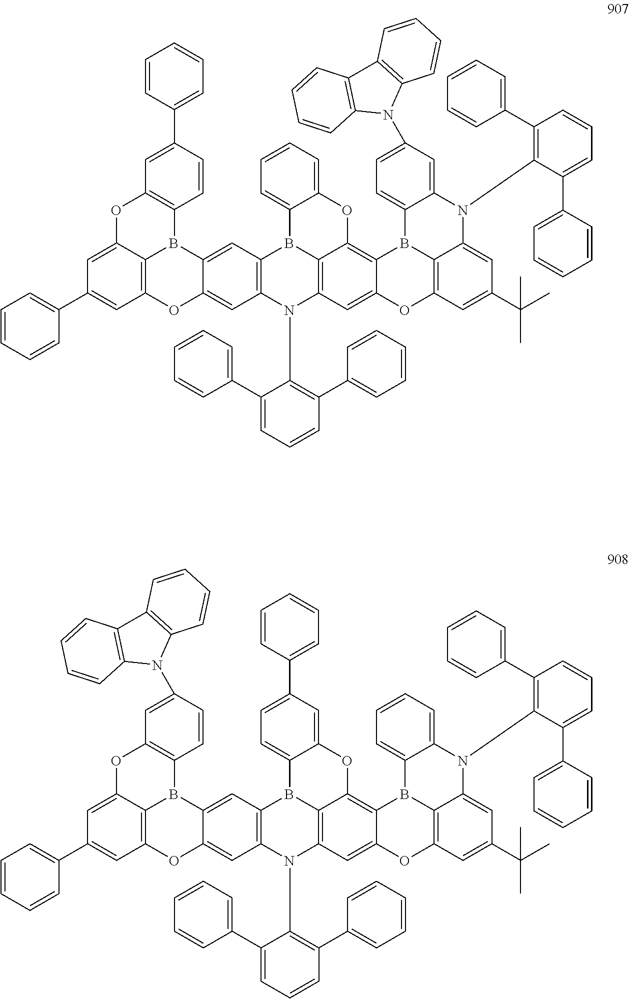 [SMILES: CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-c4ccccc4)cc1O3)O2 ; CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1O3)O2] 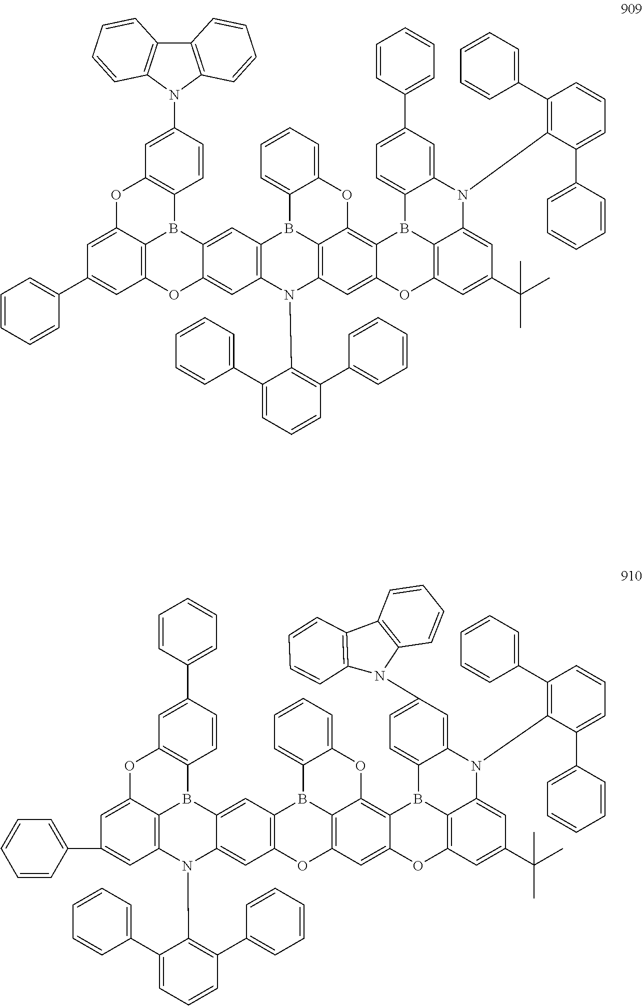 [SMILES: CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1N3c1c(-c3ccccc3)cccc1-c1ccccc1)Oc1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-c4ccccc4)cc1O3)O2] 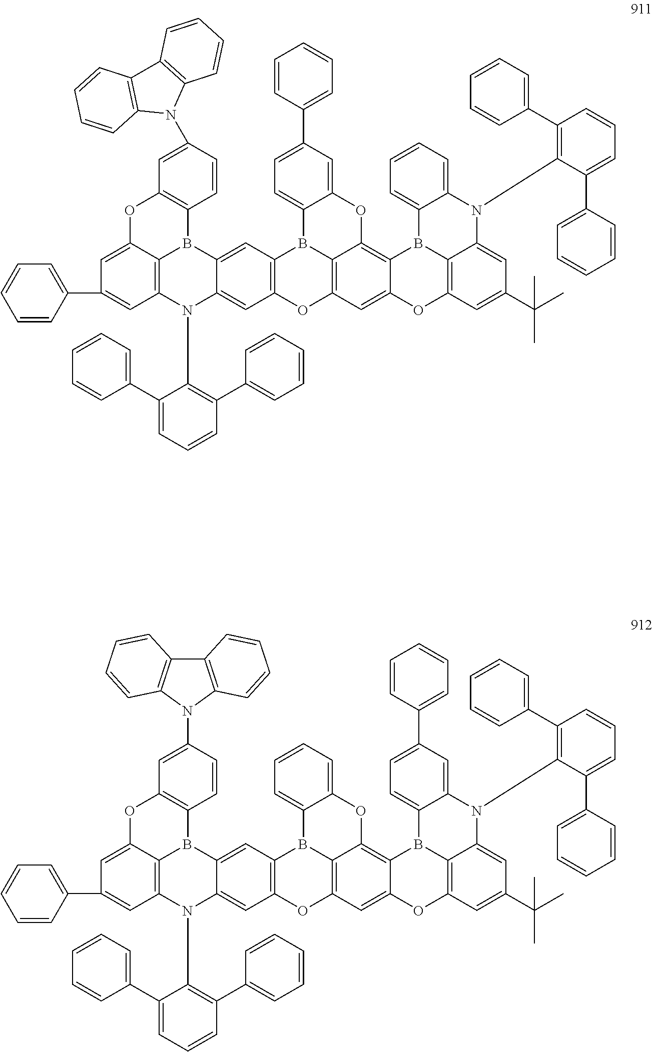 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1O3)O2] 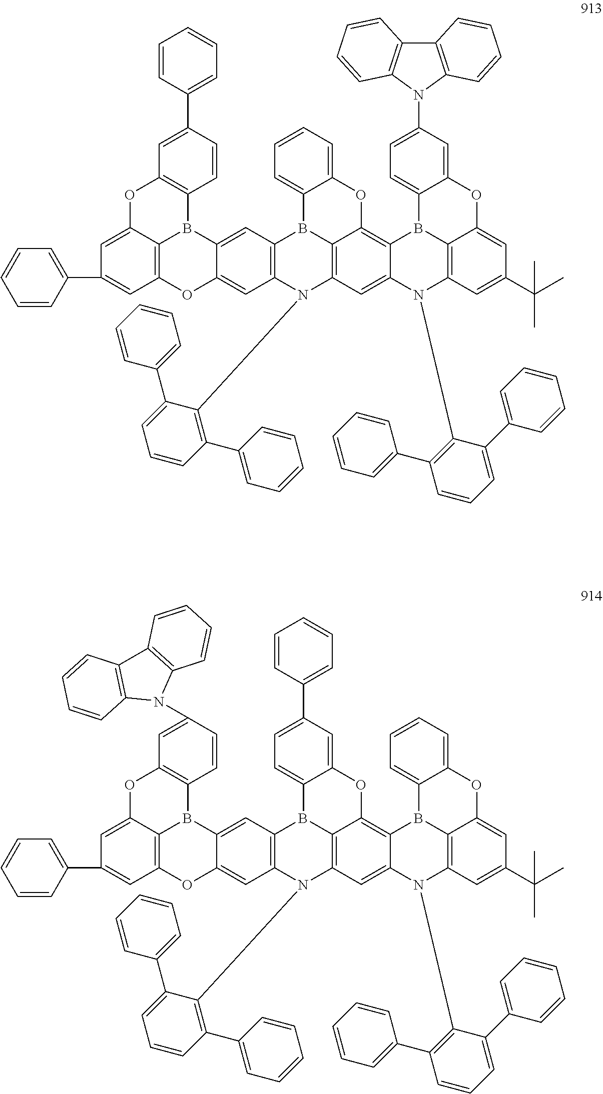 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)Oc1cc(-c3ccccc3)cc3c1B2c1ccc(-c2ccccc2)cc1O3 ; CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3] 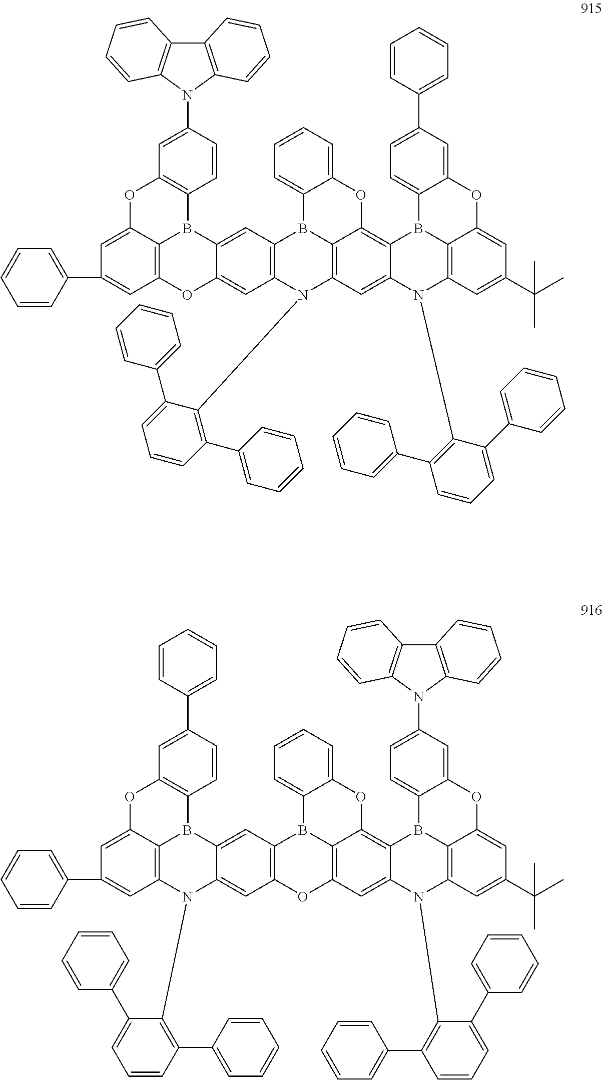 [SMILES: CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccc(-c2ccccc2)cc1O3] 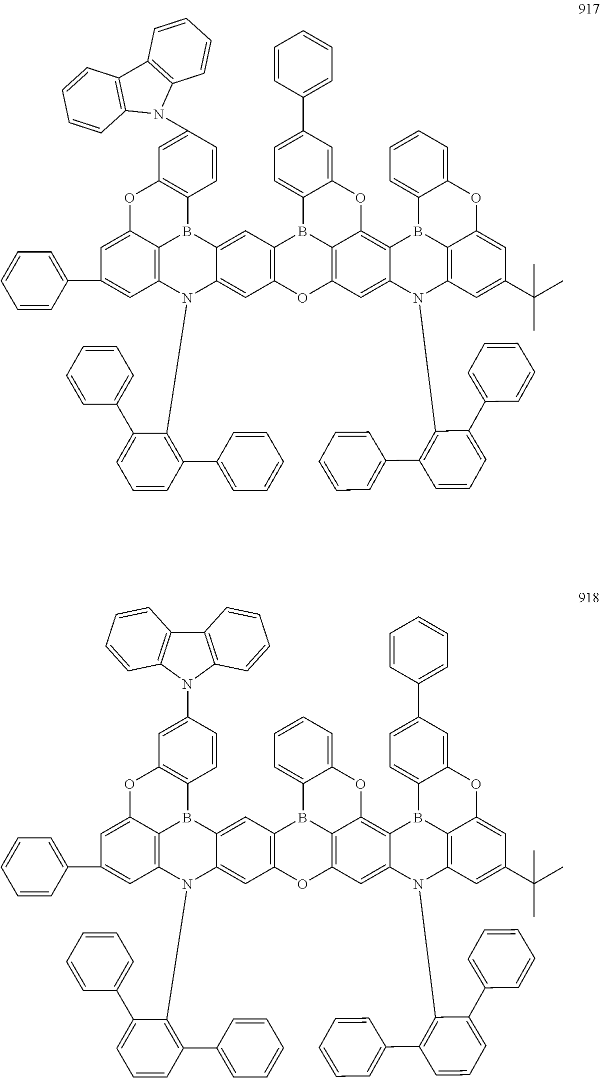 [SMILES: CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3] 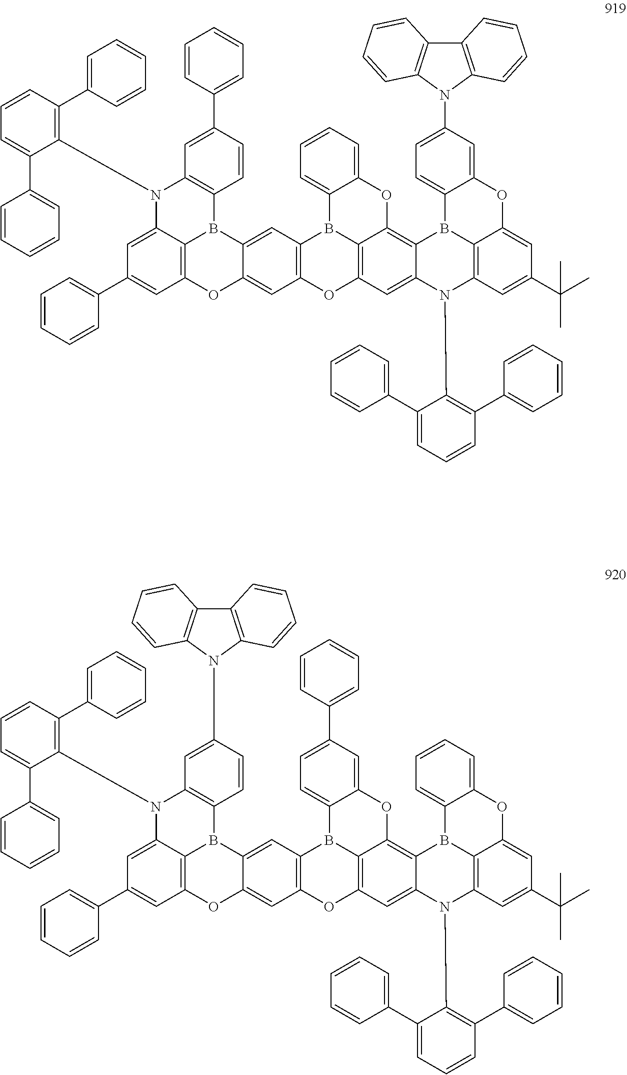 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1O2)Oc1ccccc1B5c1cc2c(cc1O4)Oc1cc(-c3ccccc3)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc4c5c(c1B3c1ccccc1O2)Oc1cc(-c2ccccc2)ccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1] 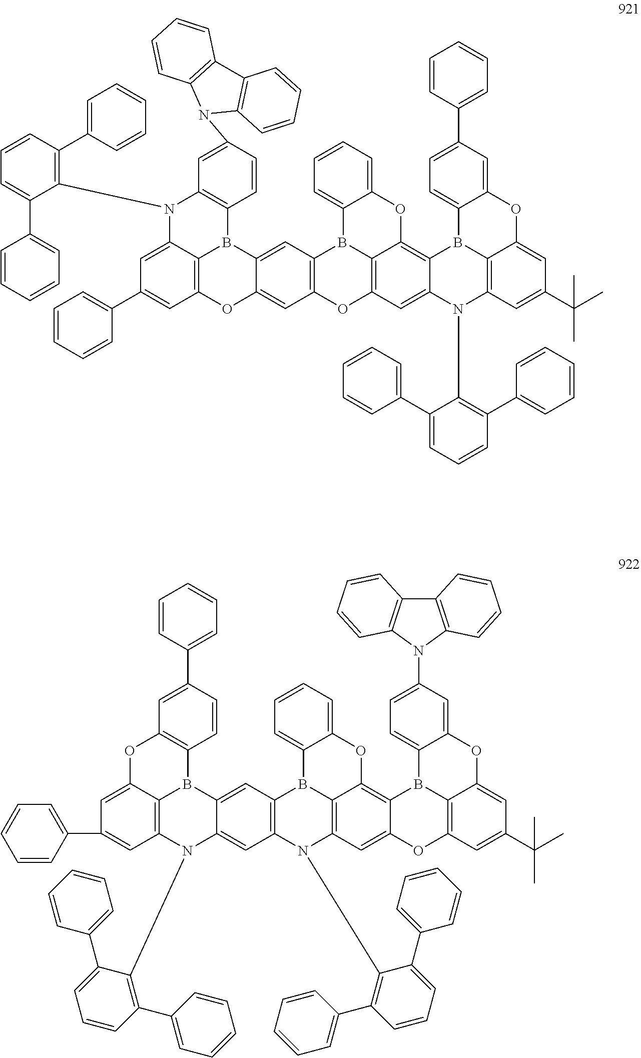 [SMILES: CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-c2ccccc2)cc1O3] 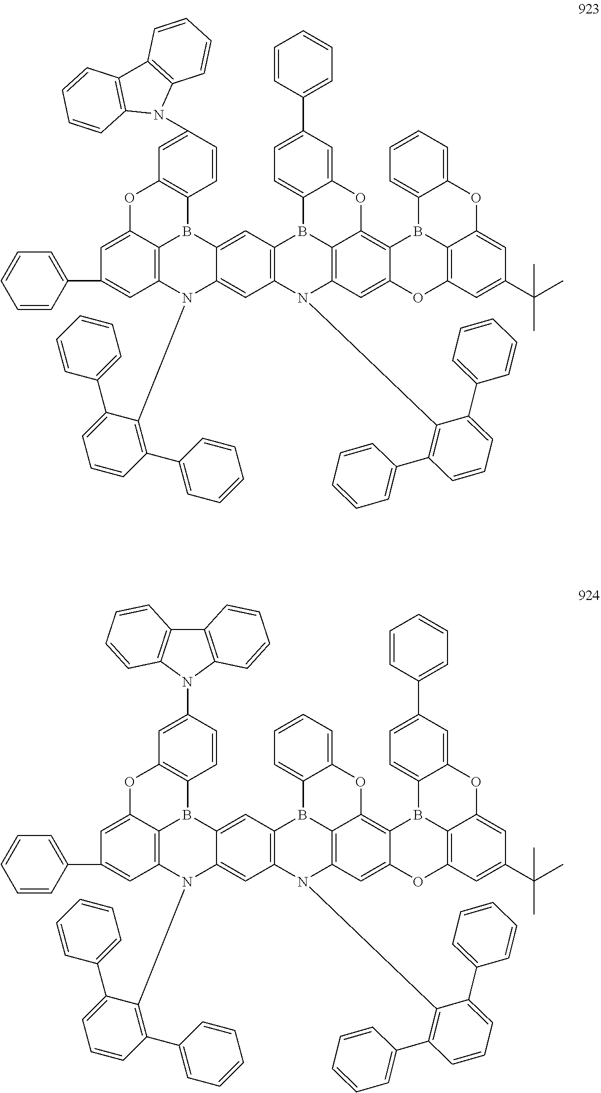 [SMILES: CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1O3 ; CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-n2c4ccccc4c4ccccc42)cc1O3] 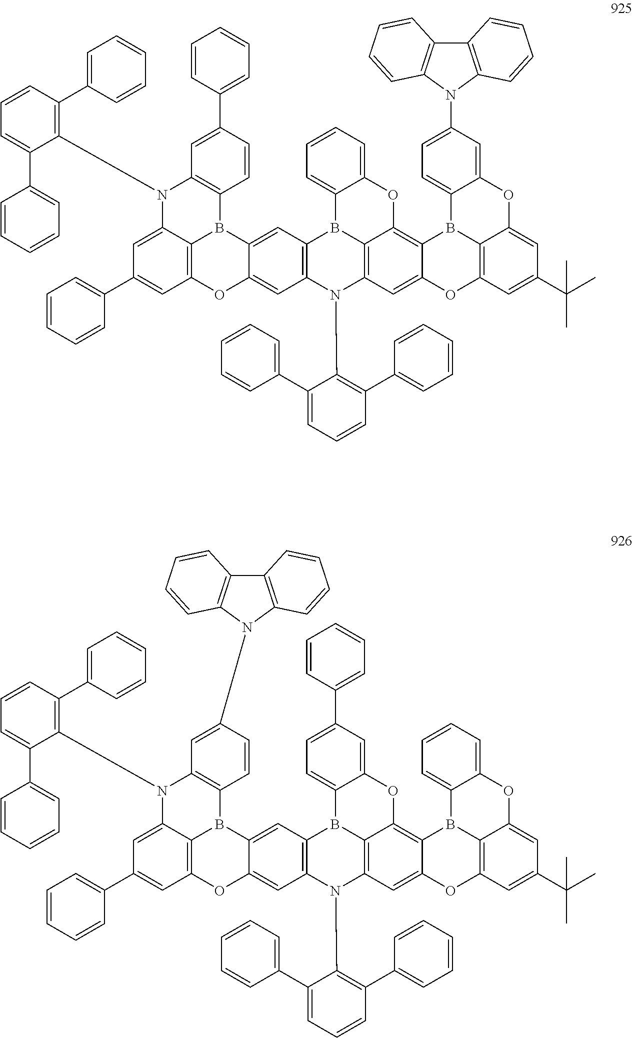 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1c(-c3ccccc3)cccc1-c1ccccc1)Oc1cc(-c3ccccc3)cc3c1B2c1ccc(-c2ccccc2)cc1N3c1c(-c2ccccc2)cccc1-c1ccccc1 ; CC(C)(C)c1cc2c3c(c1)Oc1cc4c5c(c1B3c1ccccc1O2)Oc1cc(-c2ccccc2)ccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1N3c1c(-c2ccccc2)cccc1-c1ccccc1] 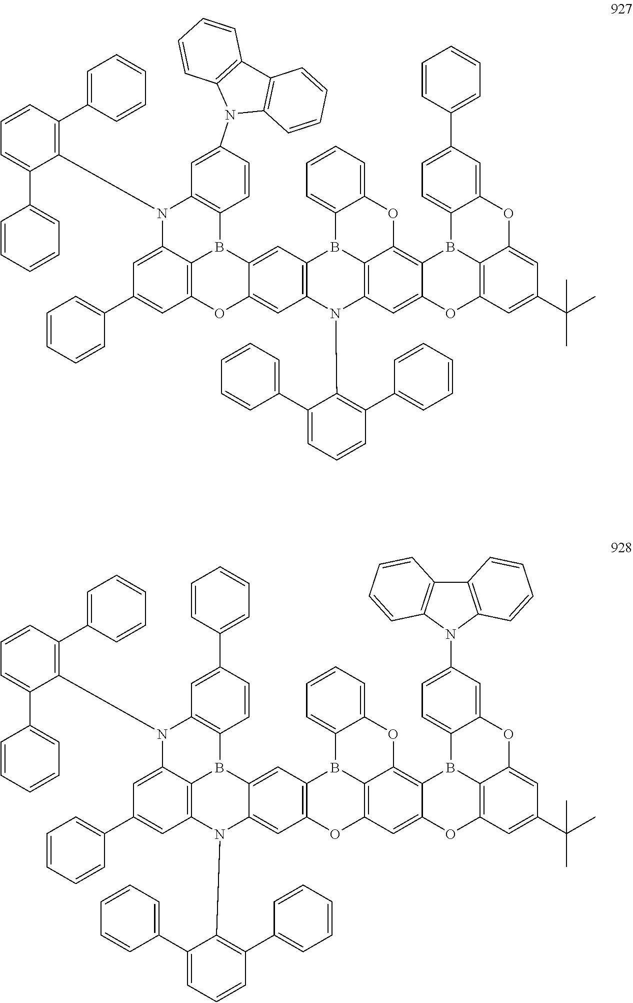 [SMILES: CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-n3c6ccccc6c6ccccc63)cc1O2)Oc1ccccc1B5c1cc2c(cc1O4)N(c1c(-c3ccccc3)cccc1-c1ccccc1)c1cc(-c3ccccc3)cc3c1B2c1ccc(-c2ccccc2)cc1N3c1c(-c2ccccc2)cccc1-c1ccccc1] 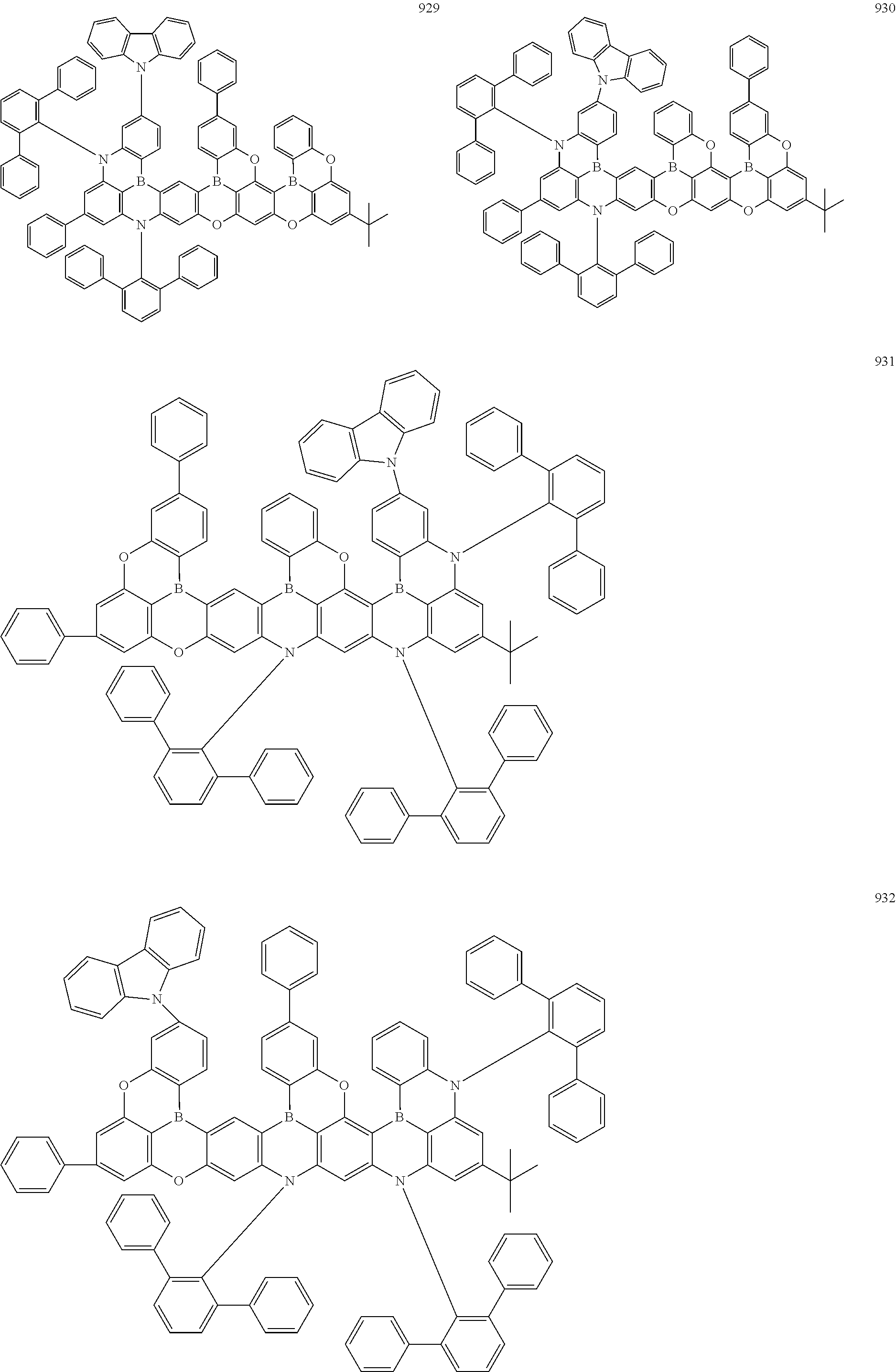 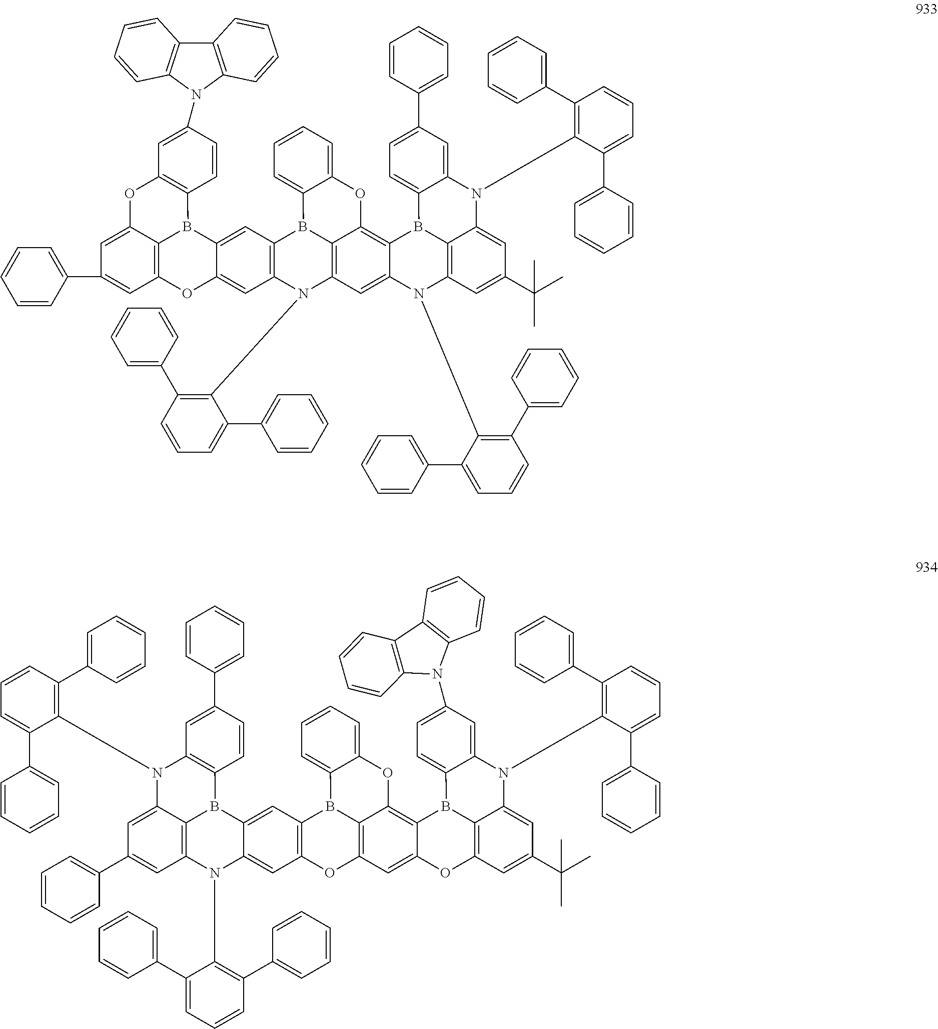 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1N4c1c(-c3ccccc3)cccc1-c1ccccc1)Oc1cc(-c3ccccc3)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-c4ccccc4)cc1N3c1c(-c3ccccc3)cccc1-c1ccccc1)O2] 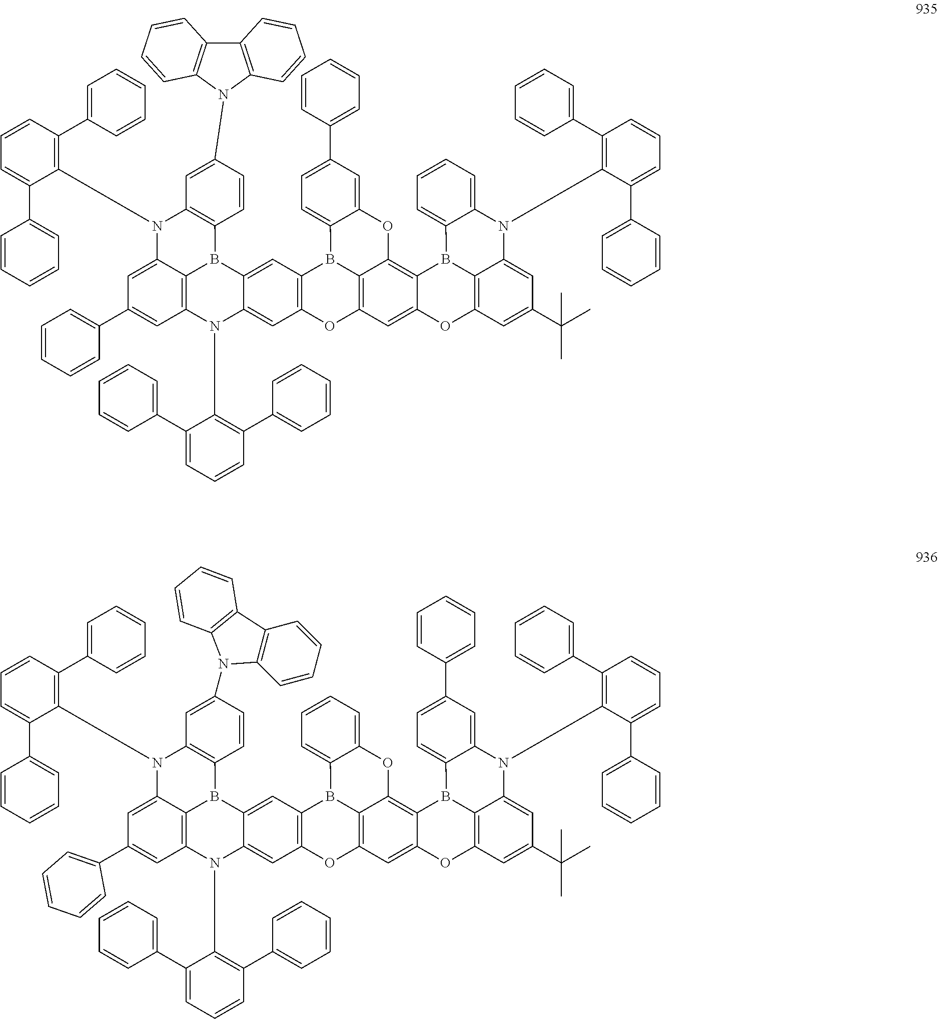 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1N3c1c(-c3ccccc3)cccc1-c1ccccc1)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1O3)N(c1c(-c3ccccc3)cccc1-c1ccccc1)c1cc(-c3ccccc3)cc3c1B4c1ccc(-n4c5ccccc5c5ccccc54)cc1N3c1c(-c3ccccc3)cccc1-c1ccccc1)O2] 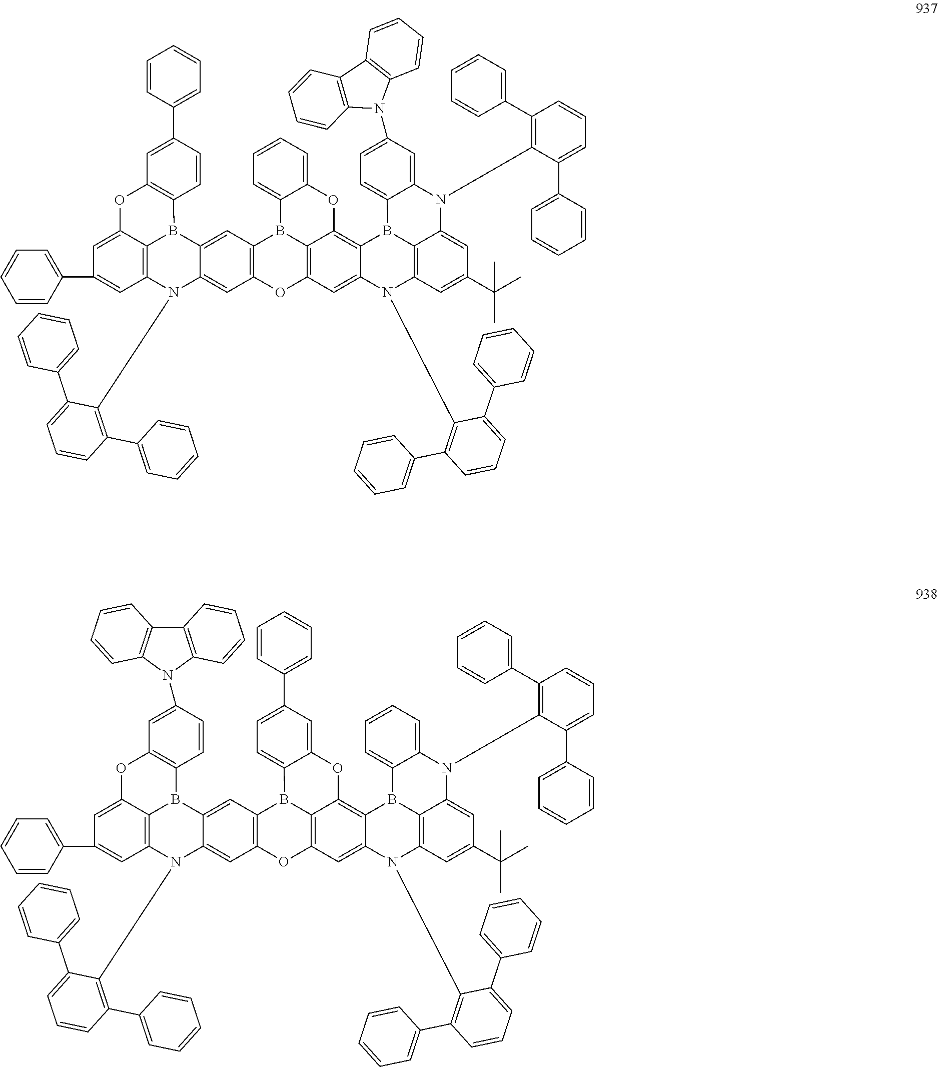 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccccc1B5c1cc2c(cc1O4)N(c1c(-c3ccccc3)cccc1-c1ccccc1)c1cc(-c3ccccc3)cc3c1B2c1ccc(-c2ccccc2)cc1O3 ; CC(C)(C)c1cc2c3c(c1)N(c1c(-c4ccccc4)cccc1-c1ccccc1)c1cc4c5c(c1B3c1ccccc1N2c1c(-c2ccccc2)cccc1-c1ccccc1)Oc1cc(-c2ccccc2)ccc1B5c1cc2c(cc1O4)N(c1c(-c3ccccc3)cccc1-c1ccccc1)c1cc(-c3ccccc3)cc3c1B2c1ccc(-n2c4ccccc4c4ccccc42)cc1O3] 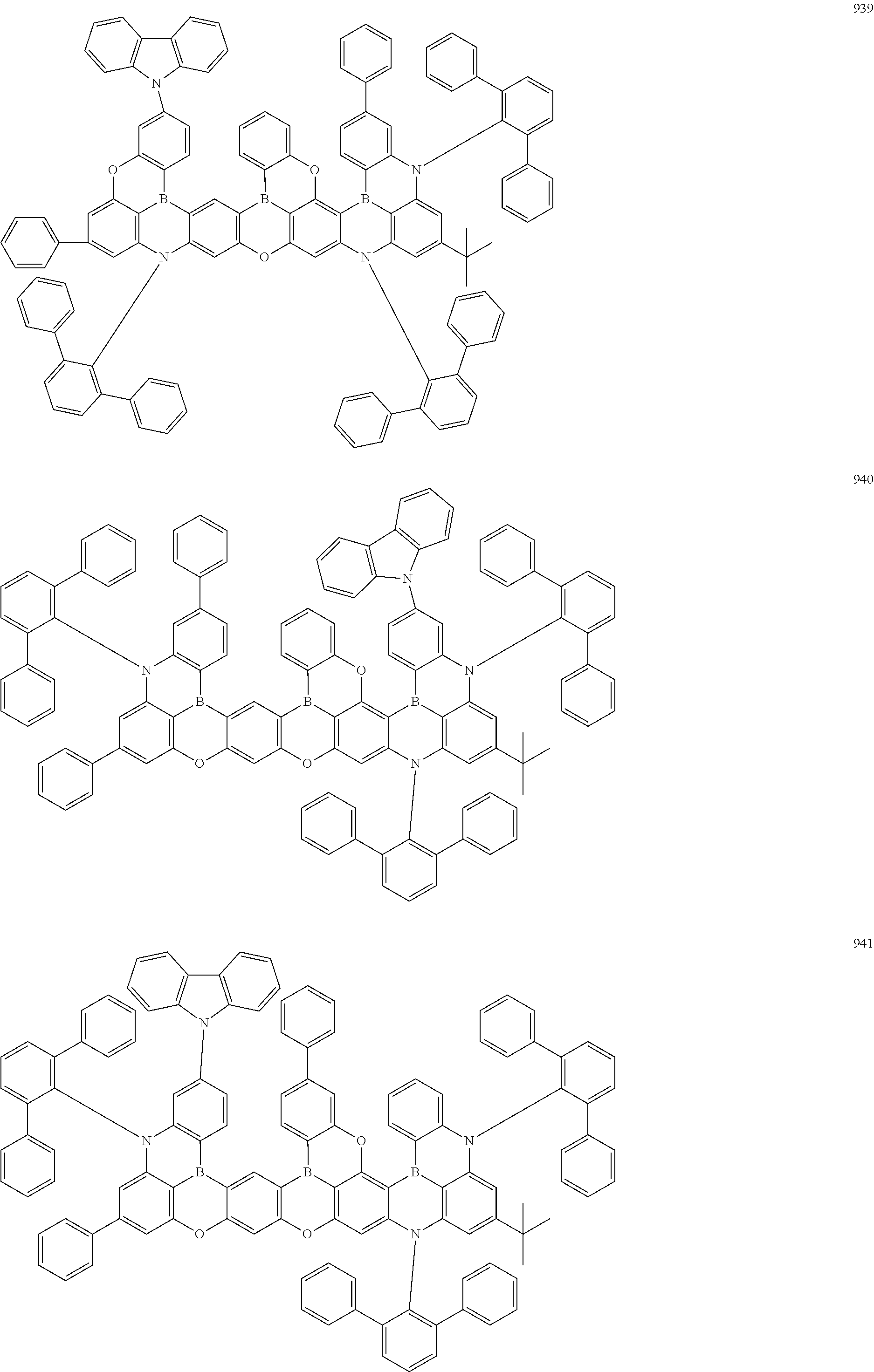 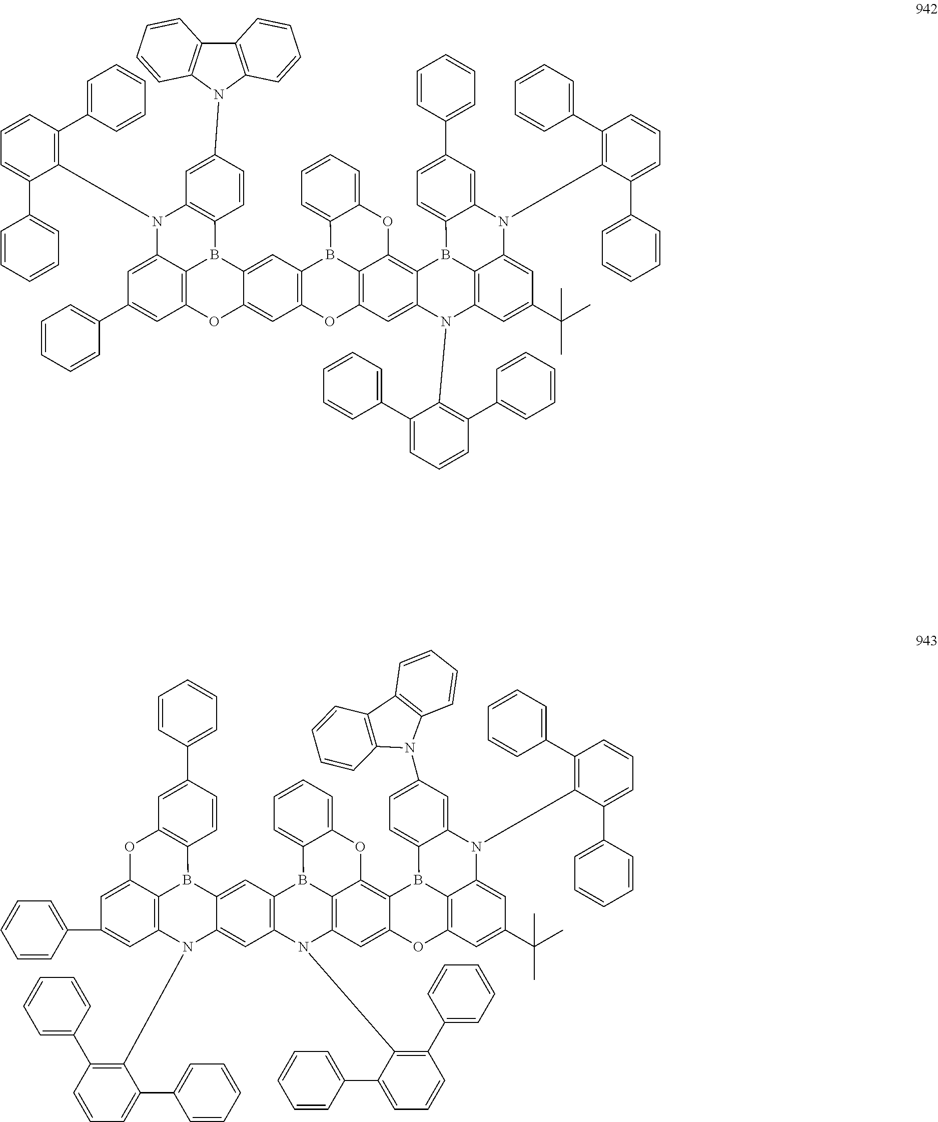 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccccc1B5c1cc2c(cc1O4)Oc1cc(-c3ccccc3)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccc(-c4ccccc4)cc1O3)O2] 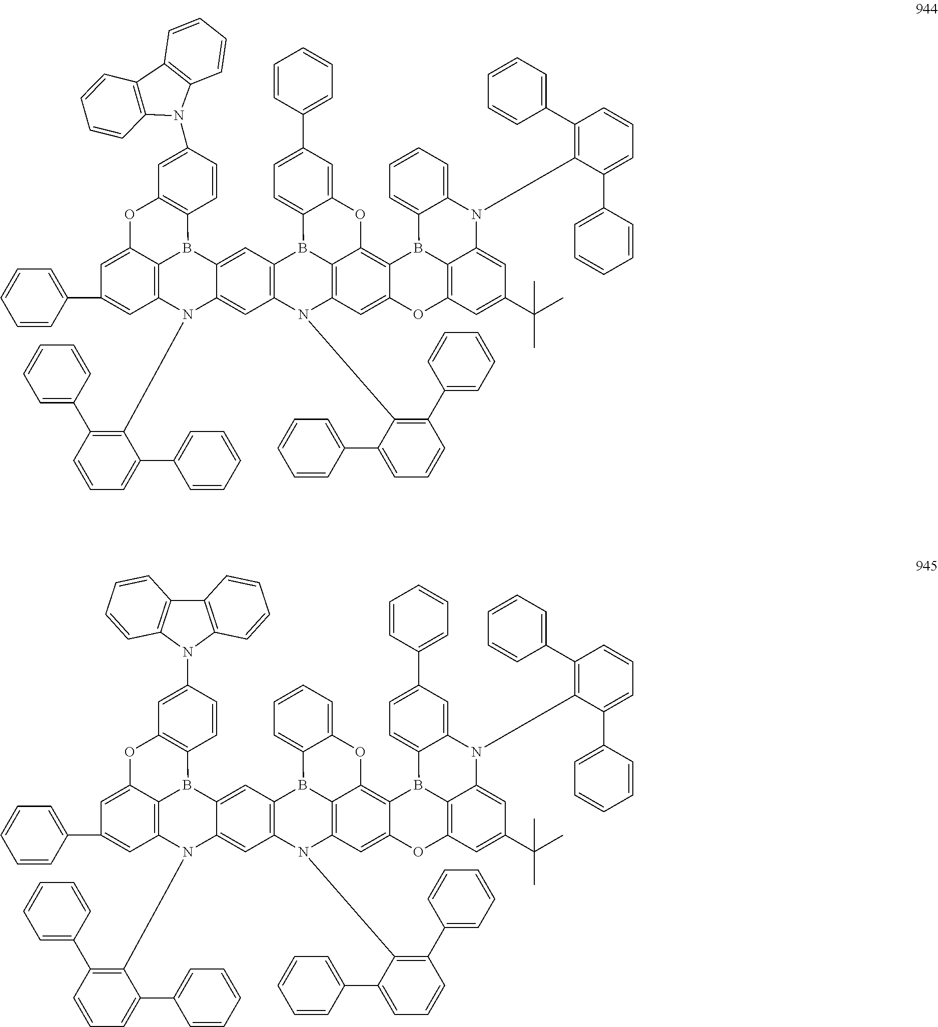 [SMILES: CC(C)(C)c1cc2c3c(c1)N(c1c(-c4ccccc4)cccc1-c1ccccc1)c1ccccc1B3c1c(cc3c4c1Oc1cc(-c5ccccc5)ccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccc(-n4c5ccccc5c5ccccc54)cc1O3)O2 ; CC(C)(C)c1cc2c3c(c1)N(c1c(-c4ccccc4)cccc1-c1ccccc1)c1cc(-c4ccccc4)ccc1B3c1c(cc3c4c1Oc1ccccc1B4c1cc4c(cc1N3c1c(-c3ccccc3)cccc1-c1ccccc1)N(c1c(-c3ccccc3)cccc1-c1ccccc1)c1cc(-c3ccccc3)cc3c1B4c1ccc(-n4c5ccccc5c5ccccc54)cc1O3)O2] 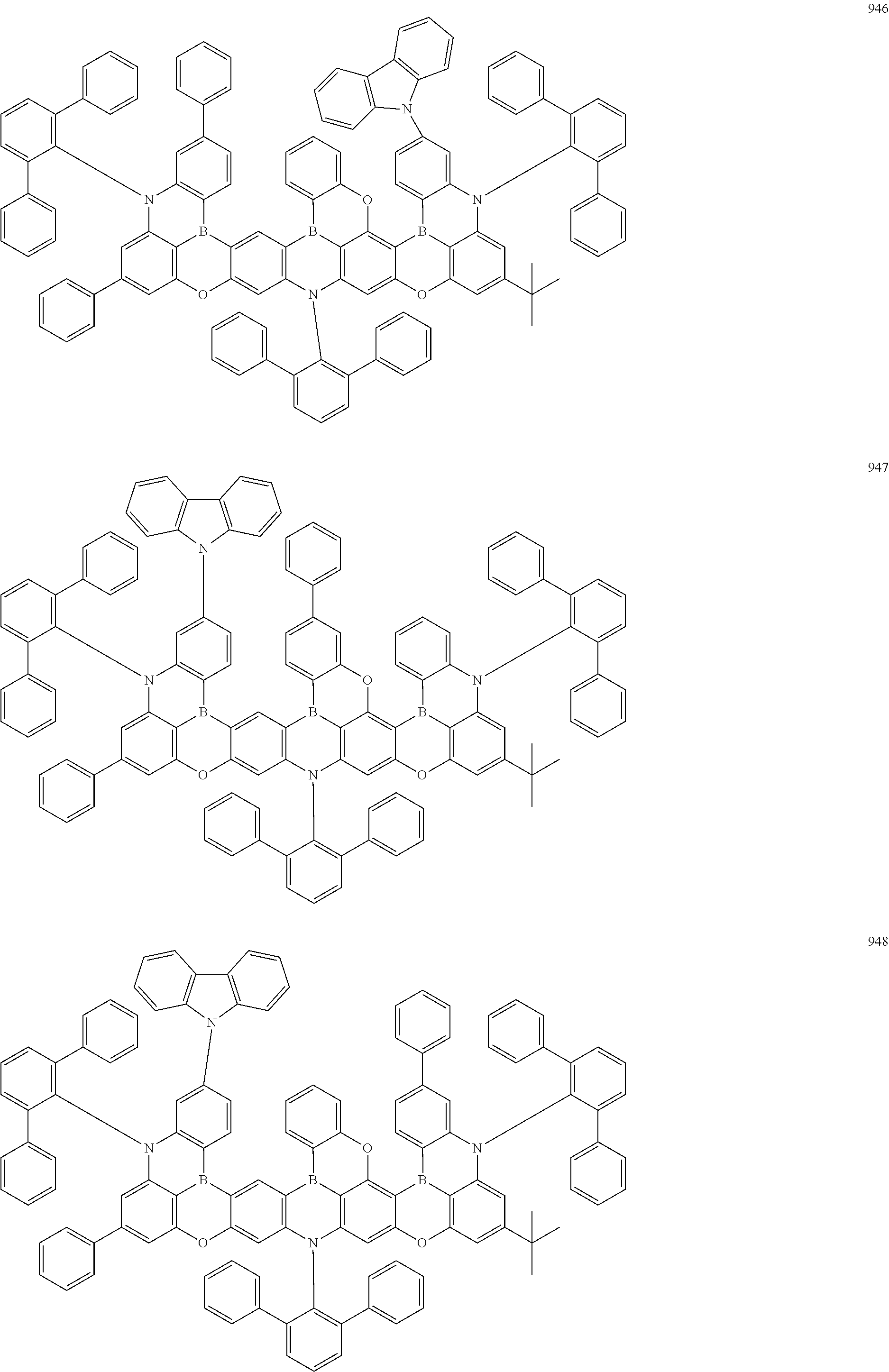 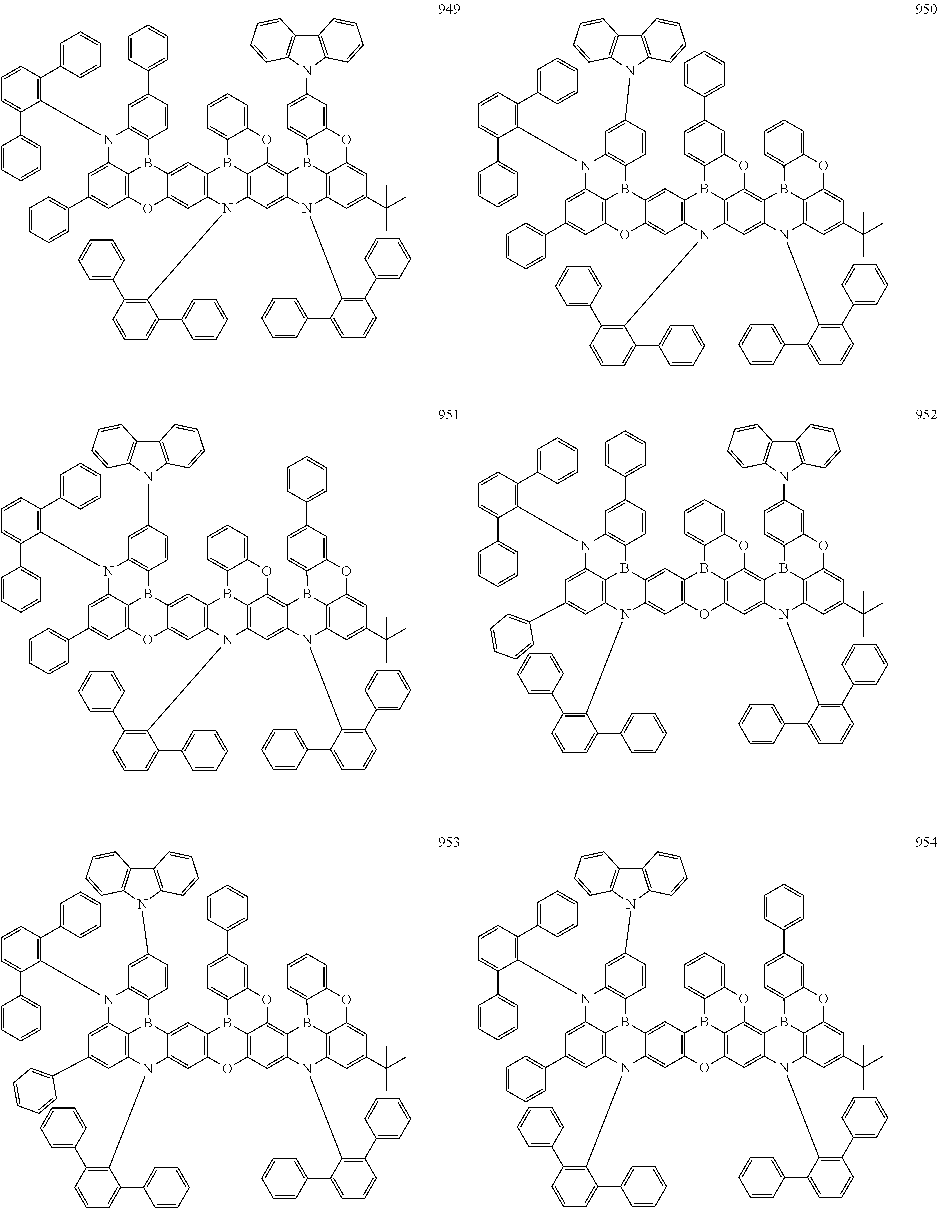 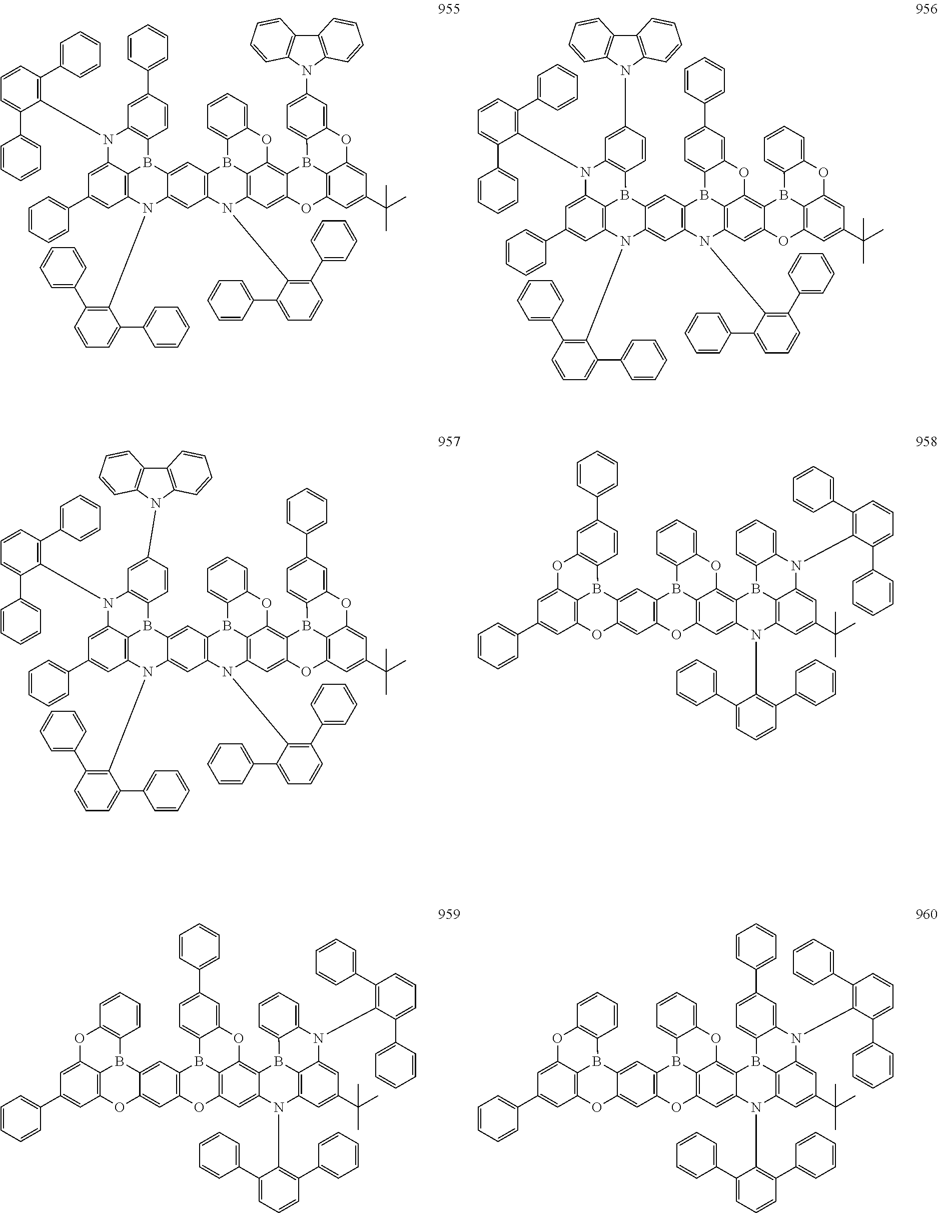 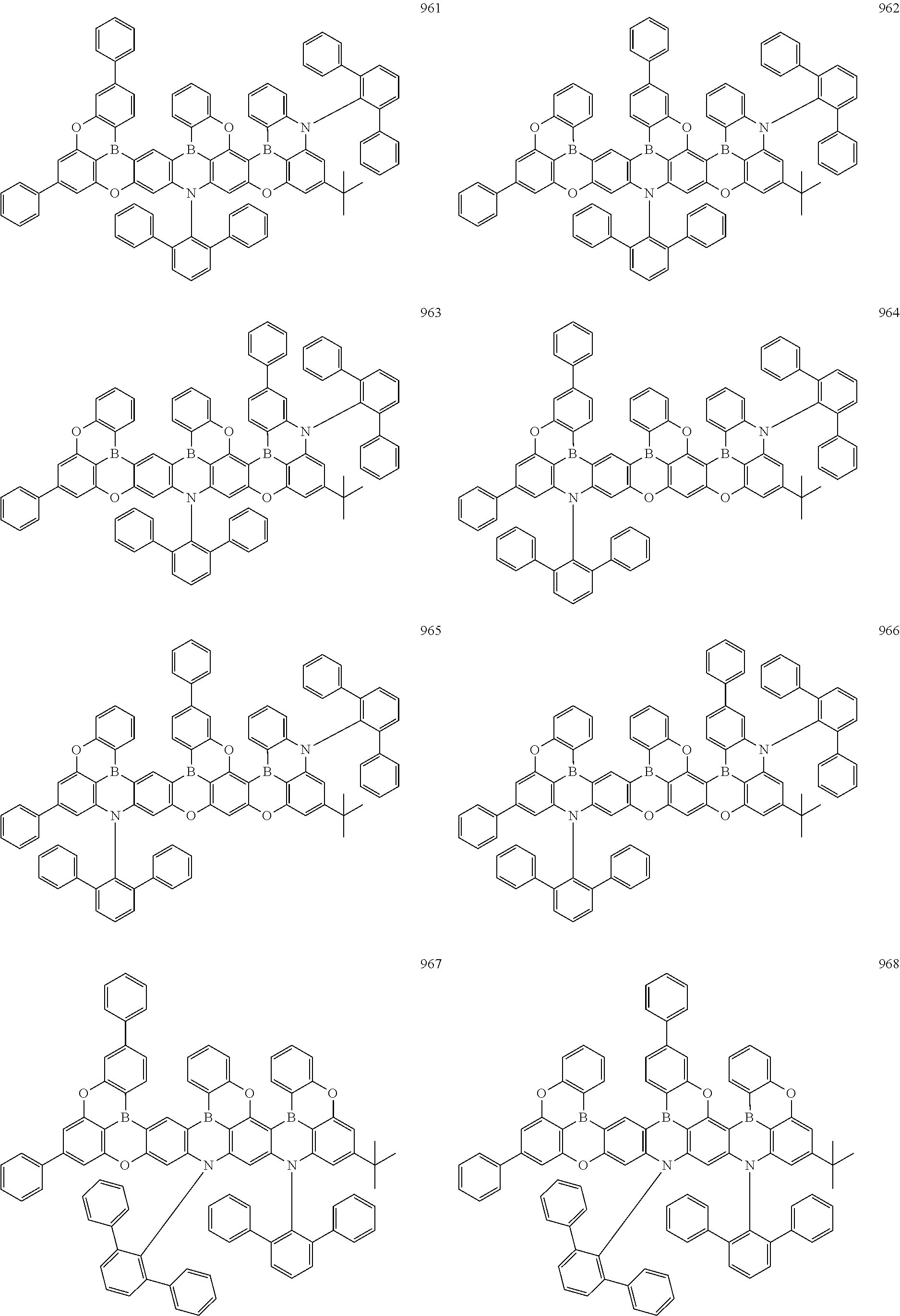 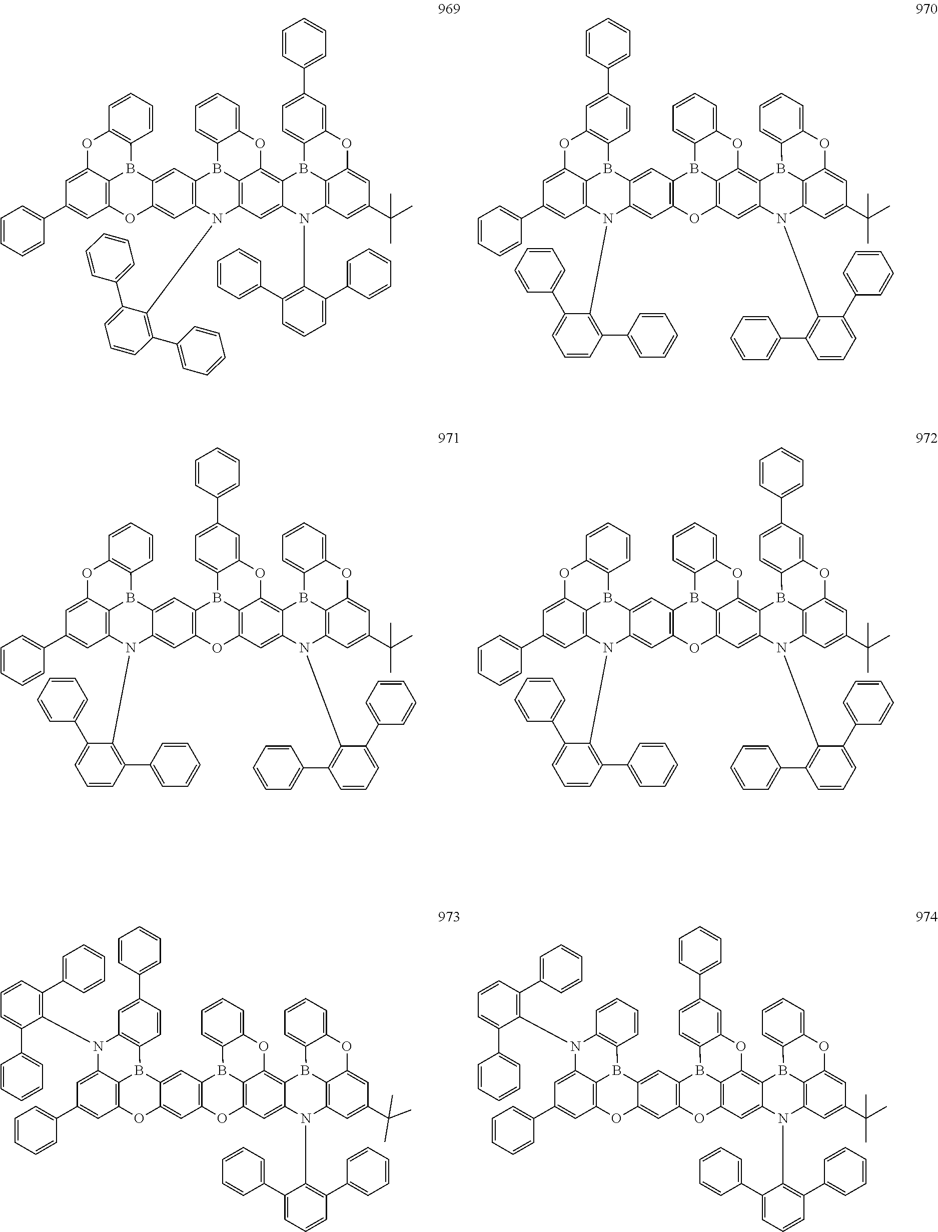 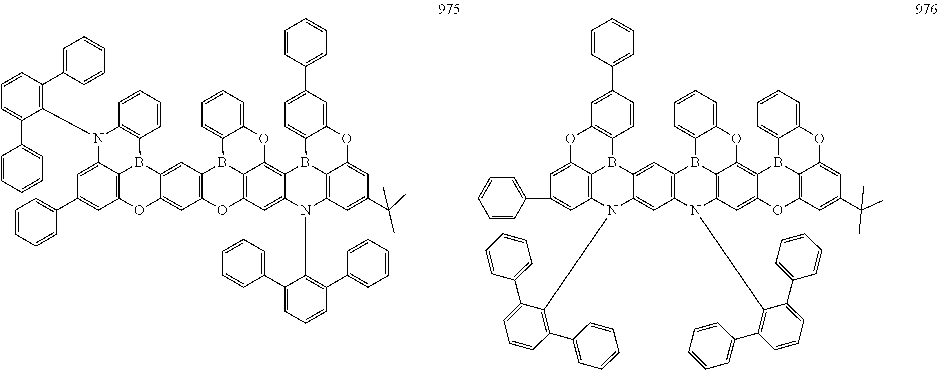 [SMILES: CC(C)(C)c1cc2c3c(c1)N(c1c(-c4ccccc4)cccc1-c1ccccc1)c1cc4c5c(c1B3c1ccc(-c3ccccc3)cc1O2)Oc1ccccc1B5c1cc2c(cc1O4)Oc1cc(-c3ccccc3)cc3c1B2c1ccccc1N3c1c(-c2ccccc2)cccc1-c1ccccc1 ; CC(C)(C)c1cc2c3c(c1)Oc1cc4c5c(c1B3c1ccccc1O2)Oc1ccccc1B5c1cc2c(cc1N4c1c(-c3ccccc3)cccc1-c1ccccc1)N(c1c(-c3ccccc3)cccc1-c1ccccc1)c1cc(-c3ccccc3)cc3c1B2c1ccc(-c2ccccc2)cc1O3] 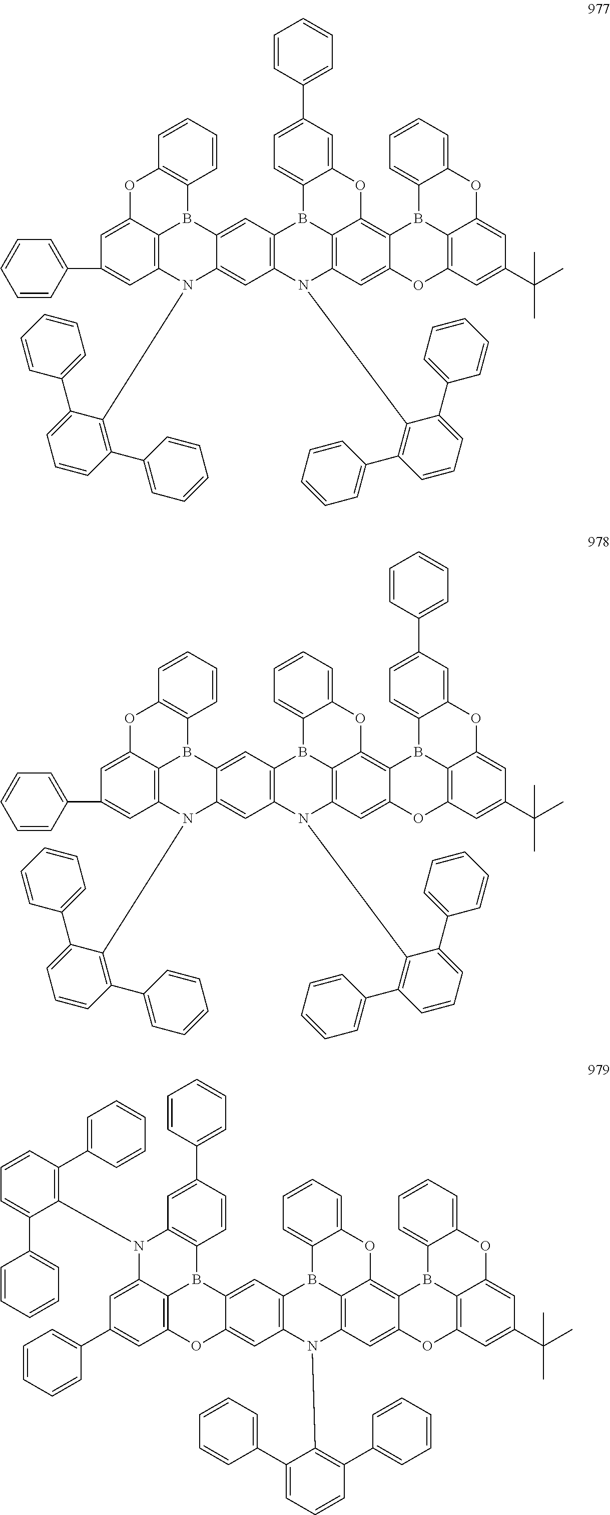 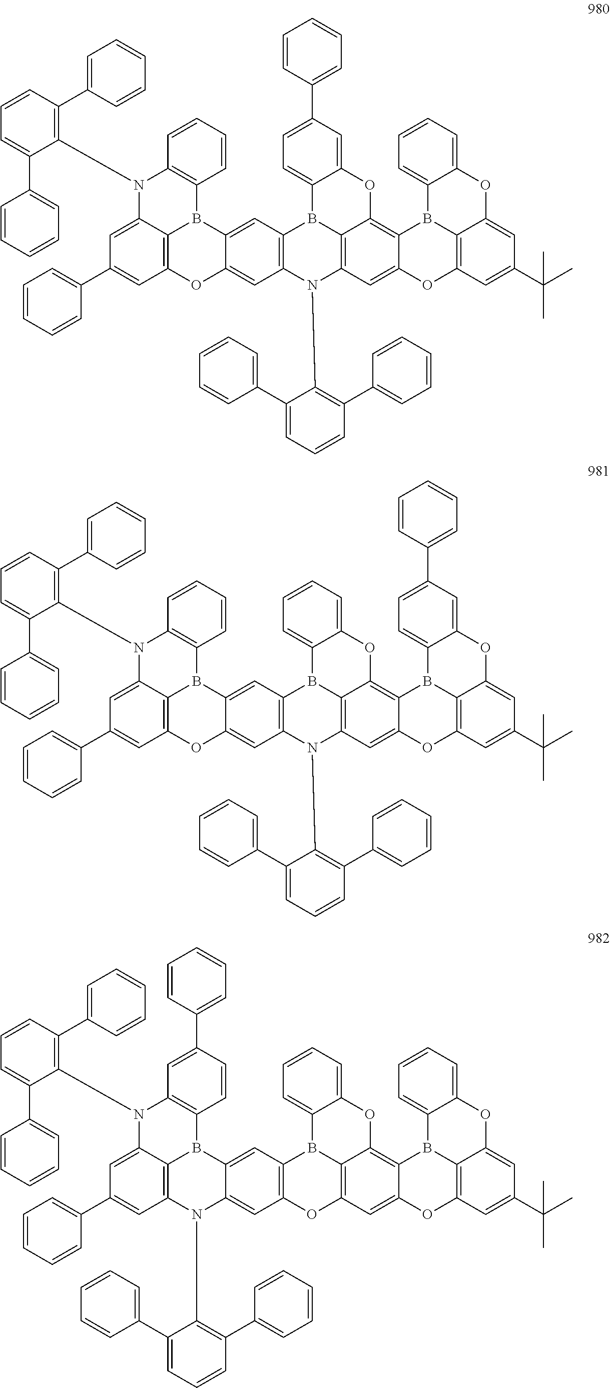 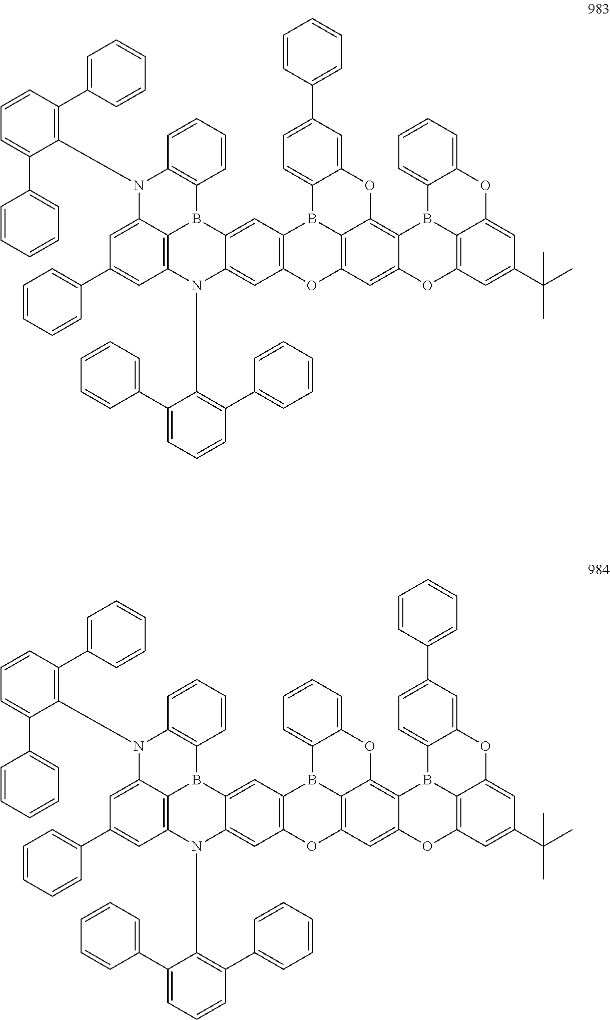 [SMILES: CC(C)(C)c1cc2c3c(c1)Oc1cc4c5c(c1B3c1ccccc1O2)Oc1cc(-c2ccccc2)ccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1O4)N(c1c(-c3ccccc3)cccc1-c1ccccc1)c1cc(-c3ccccc3)cc3c1B2c1ccccc1N3c1c(-c2ccccc2)cccc1-c1ccccc1] 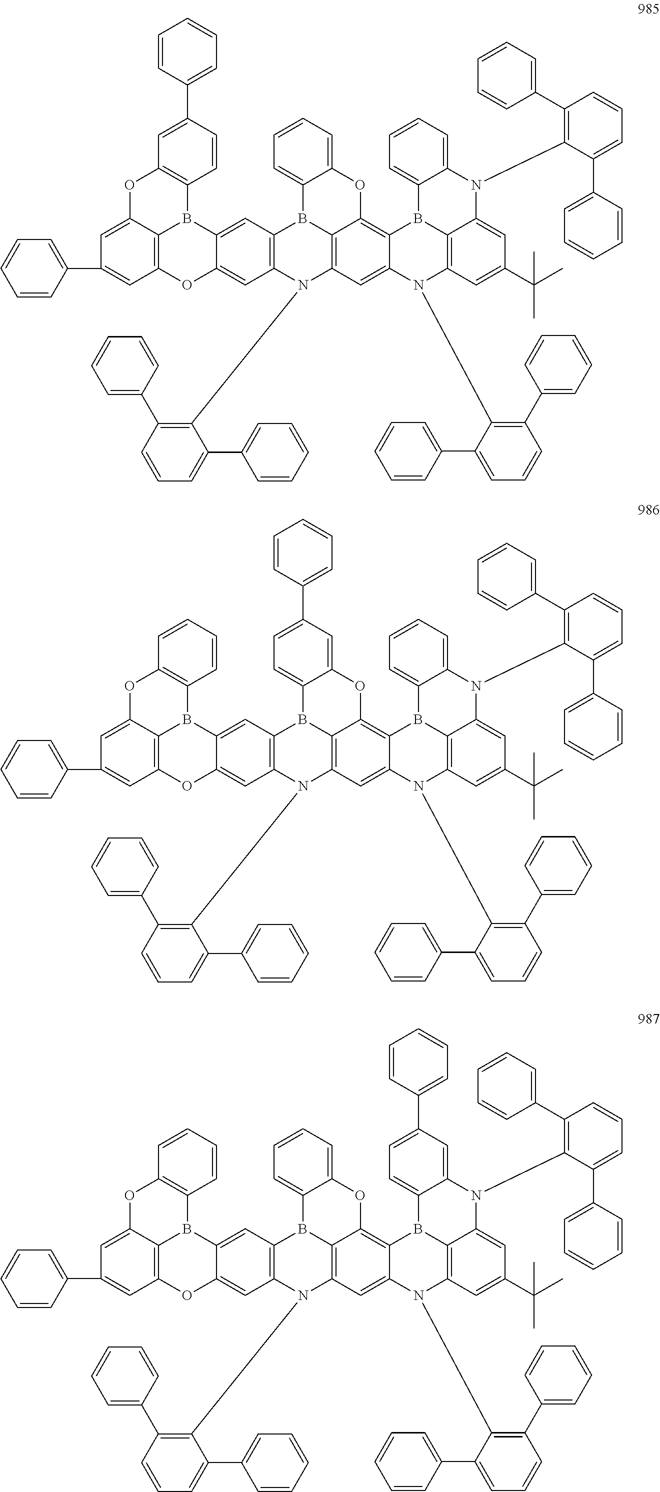 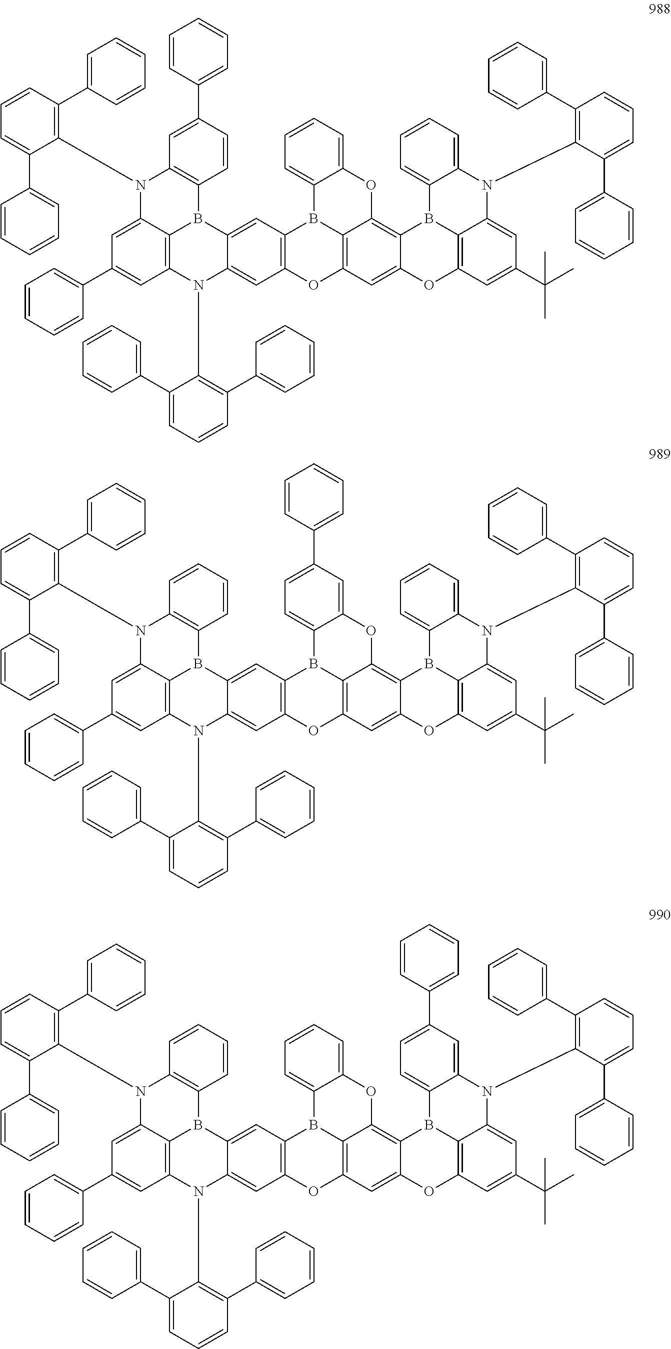 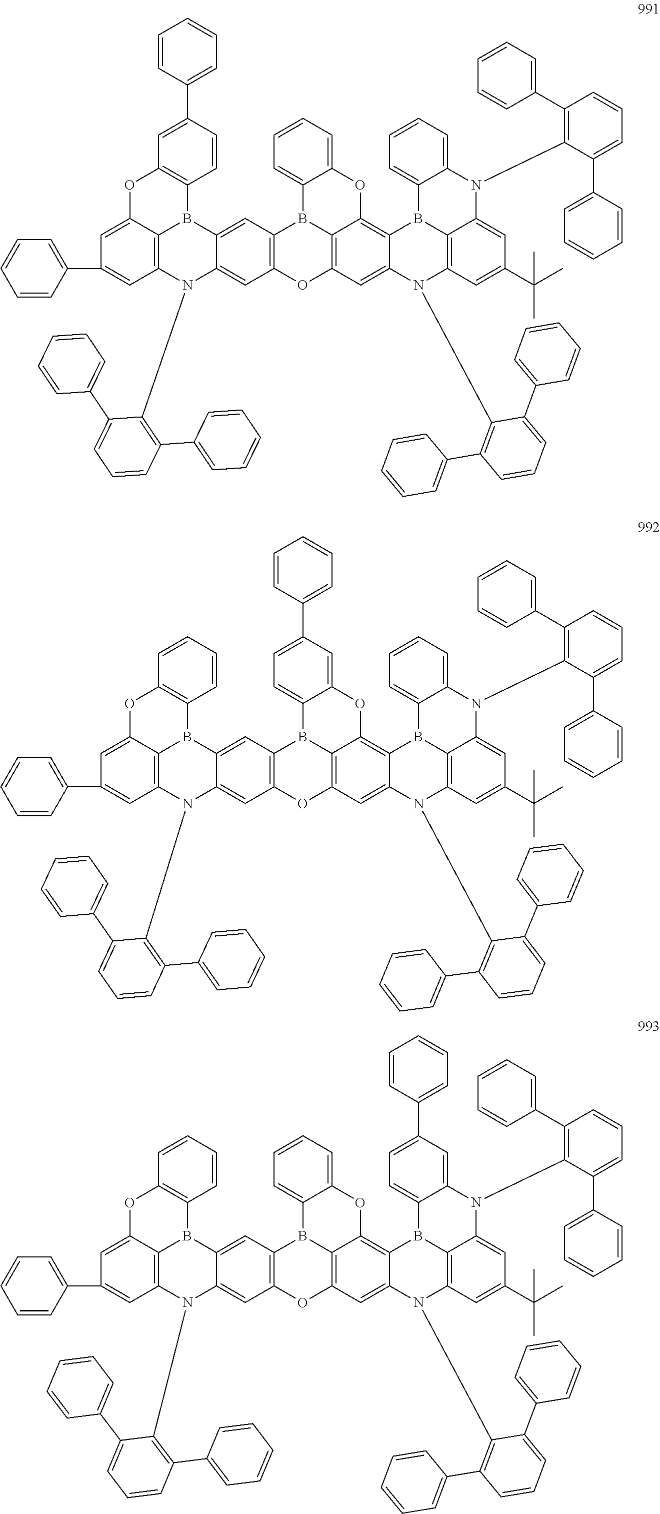 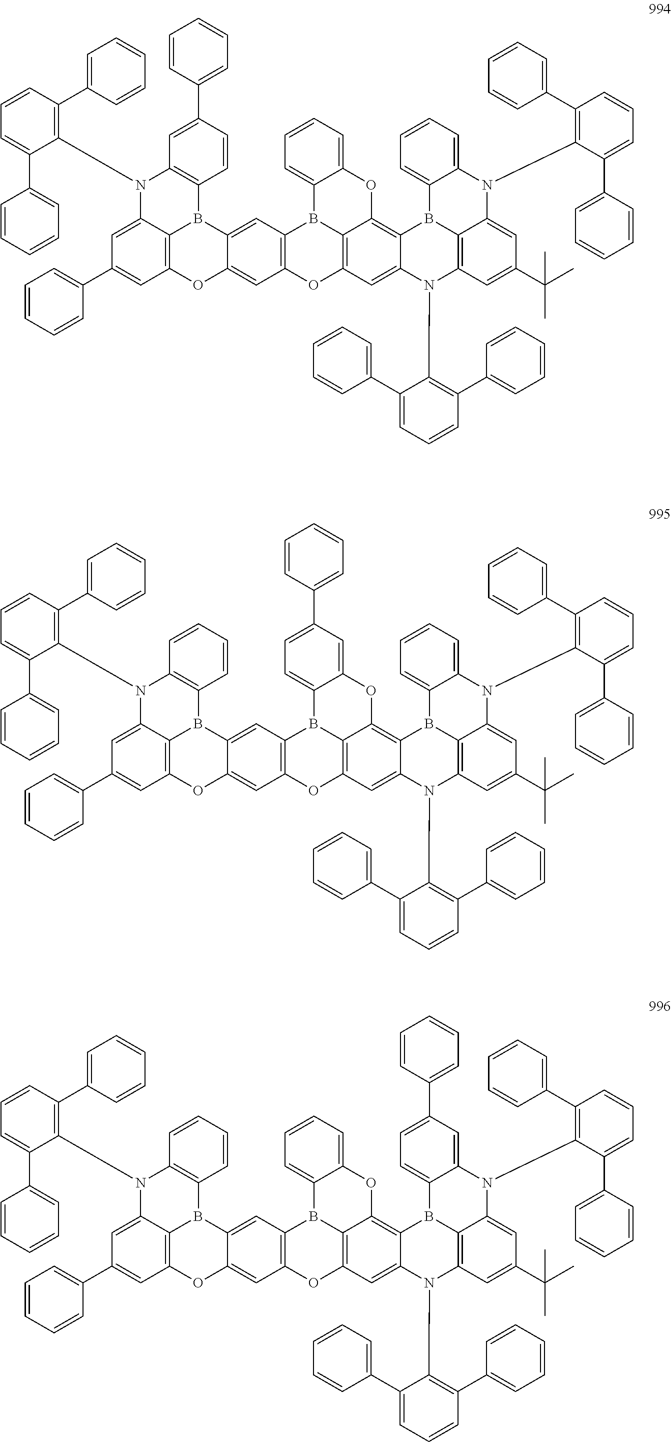 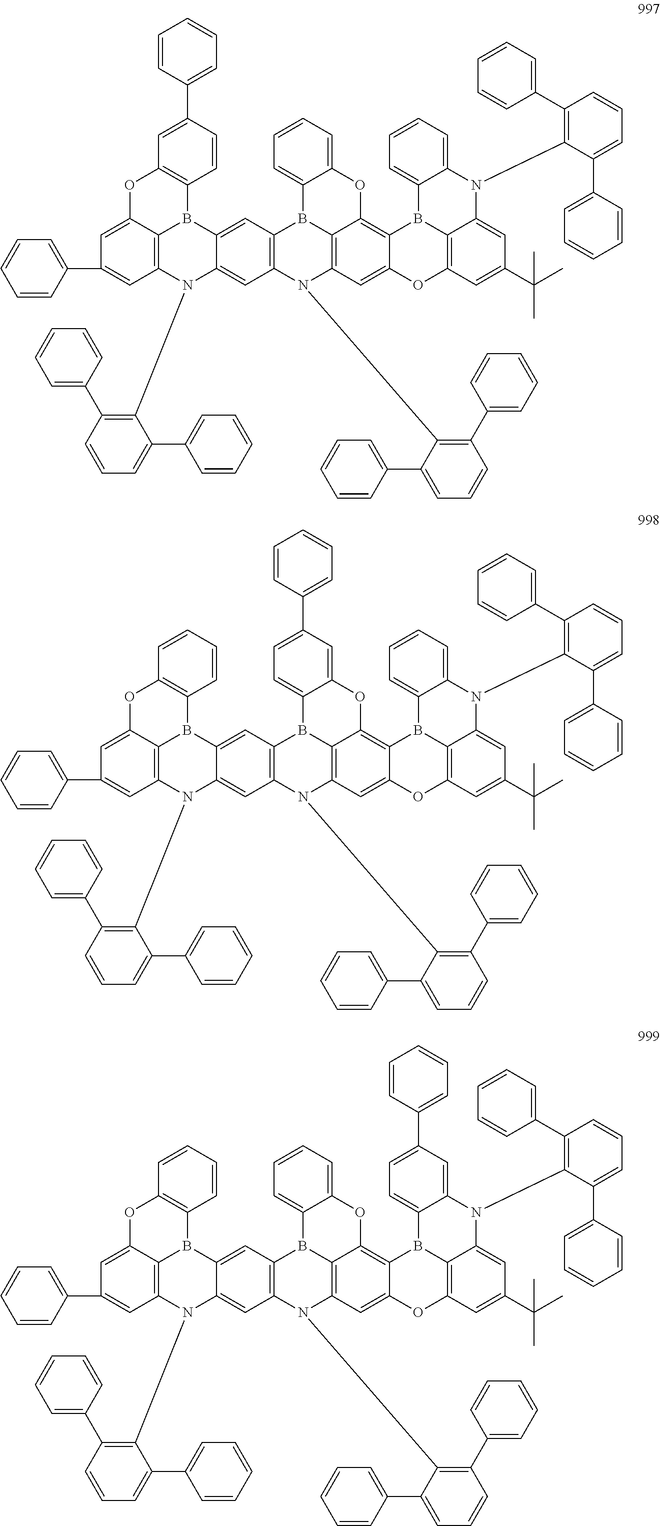 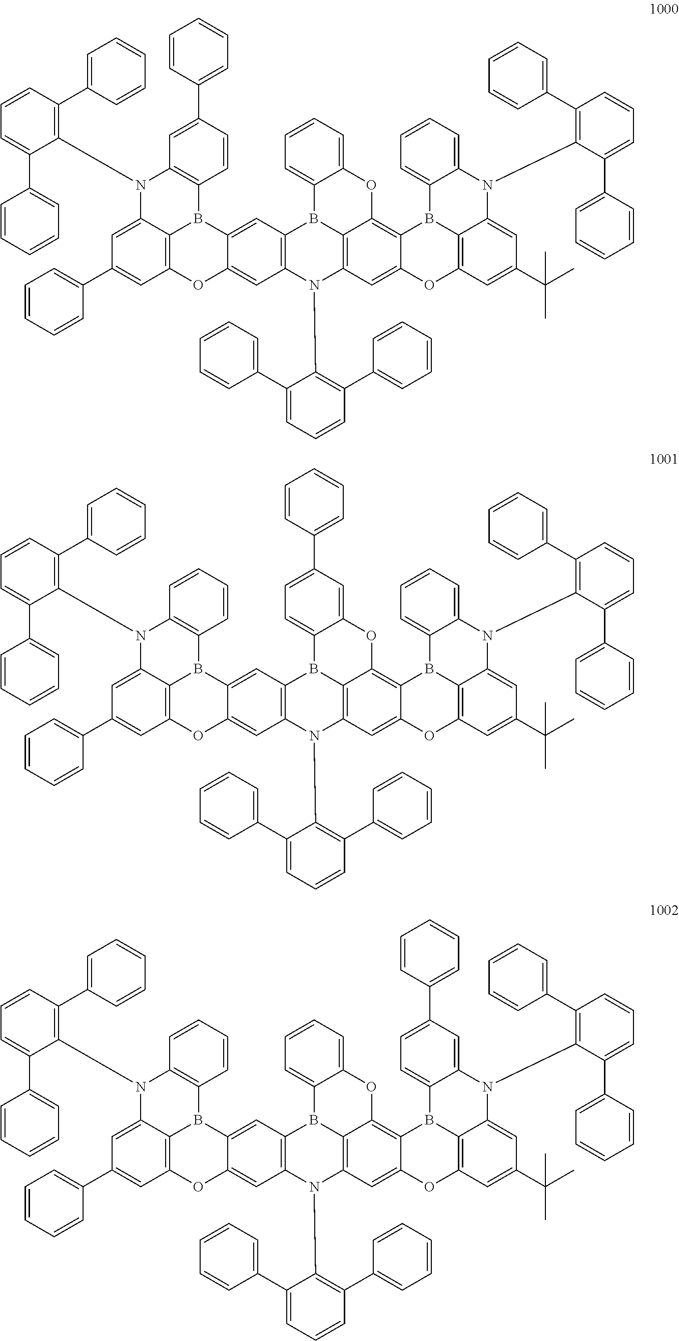 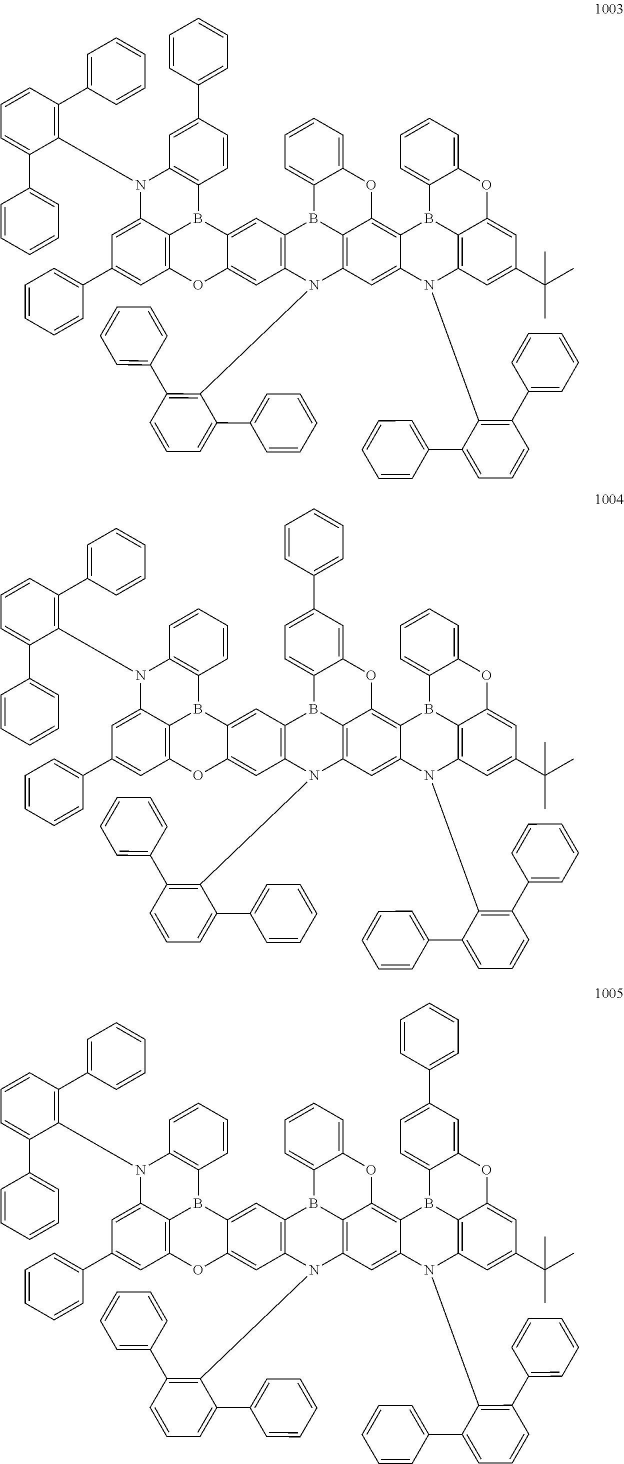 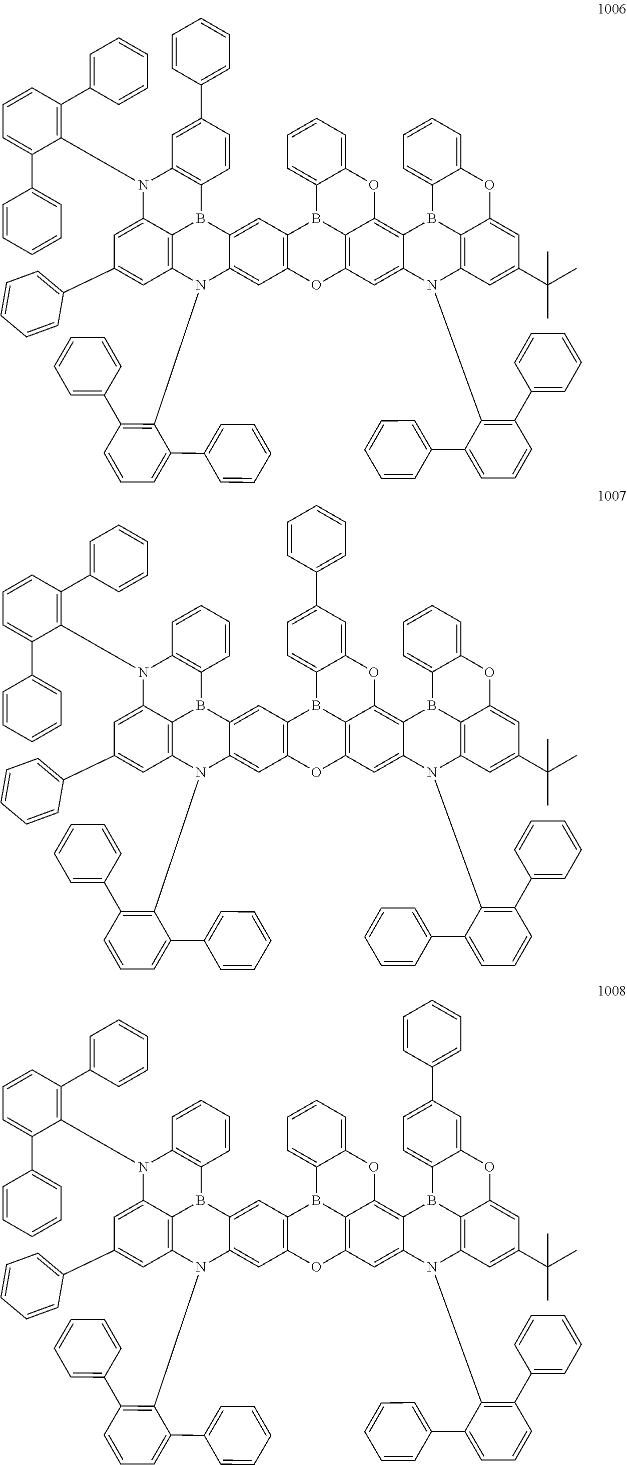 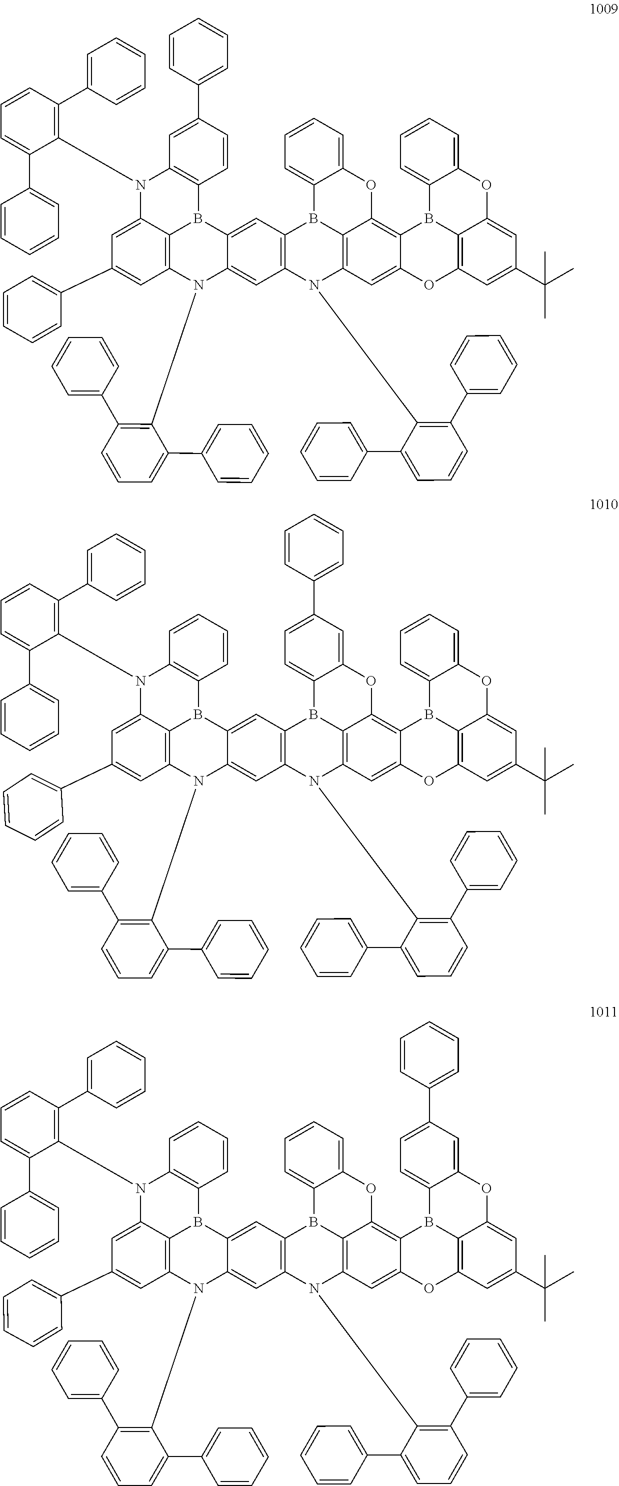 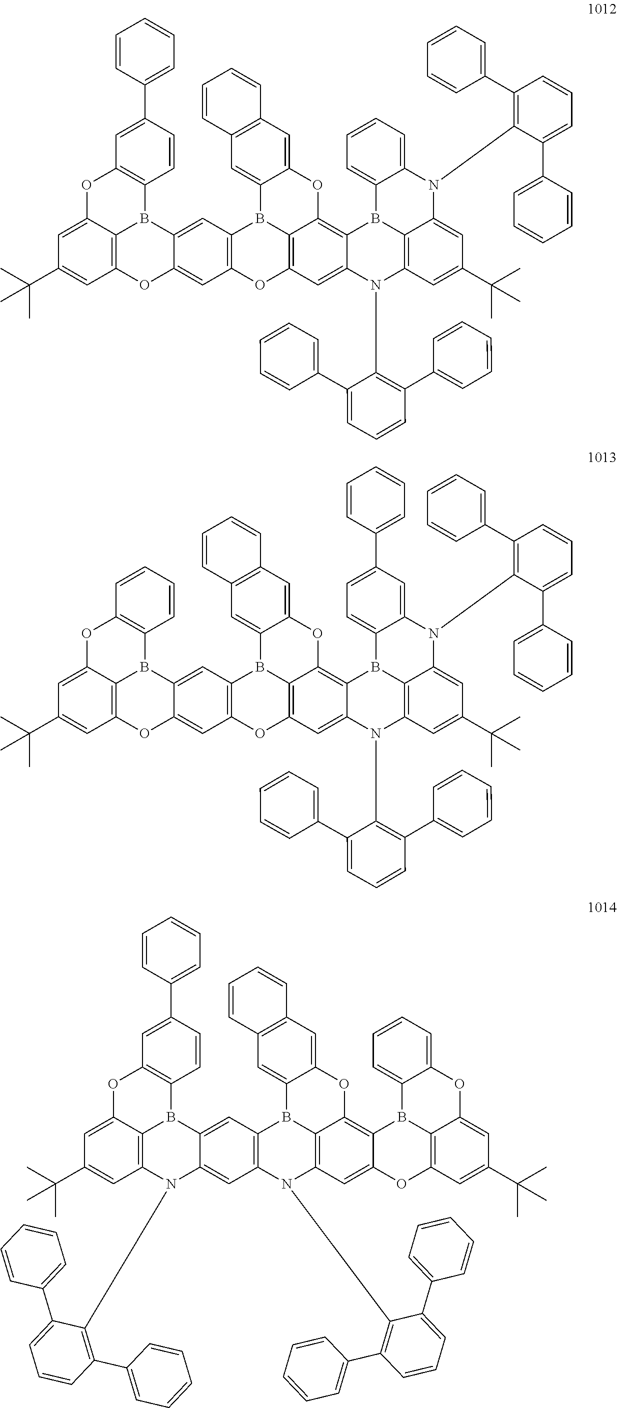 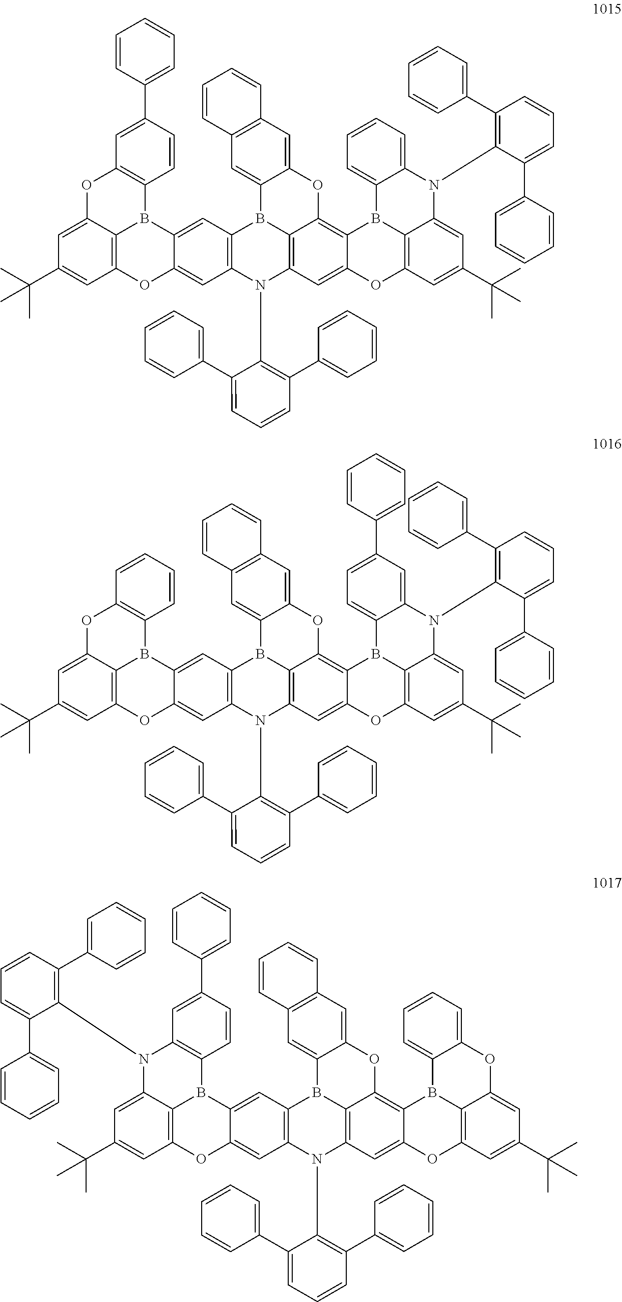 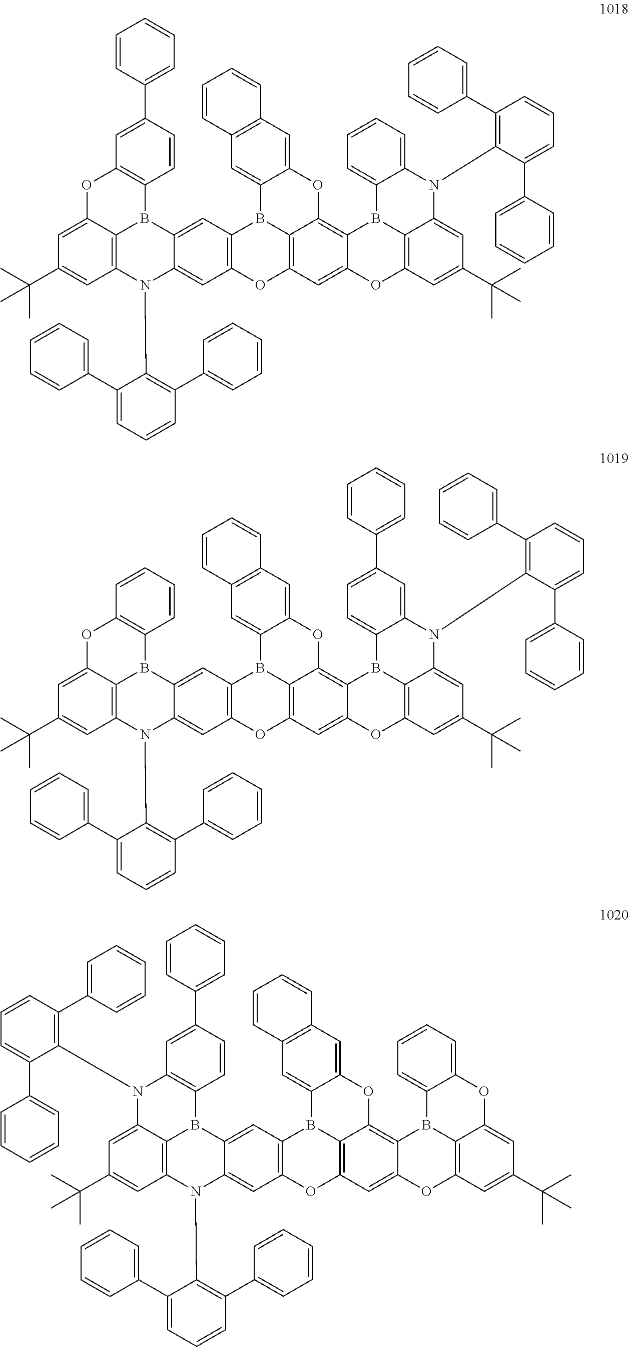 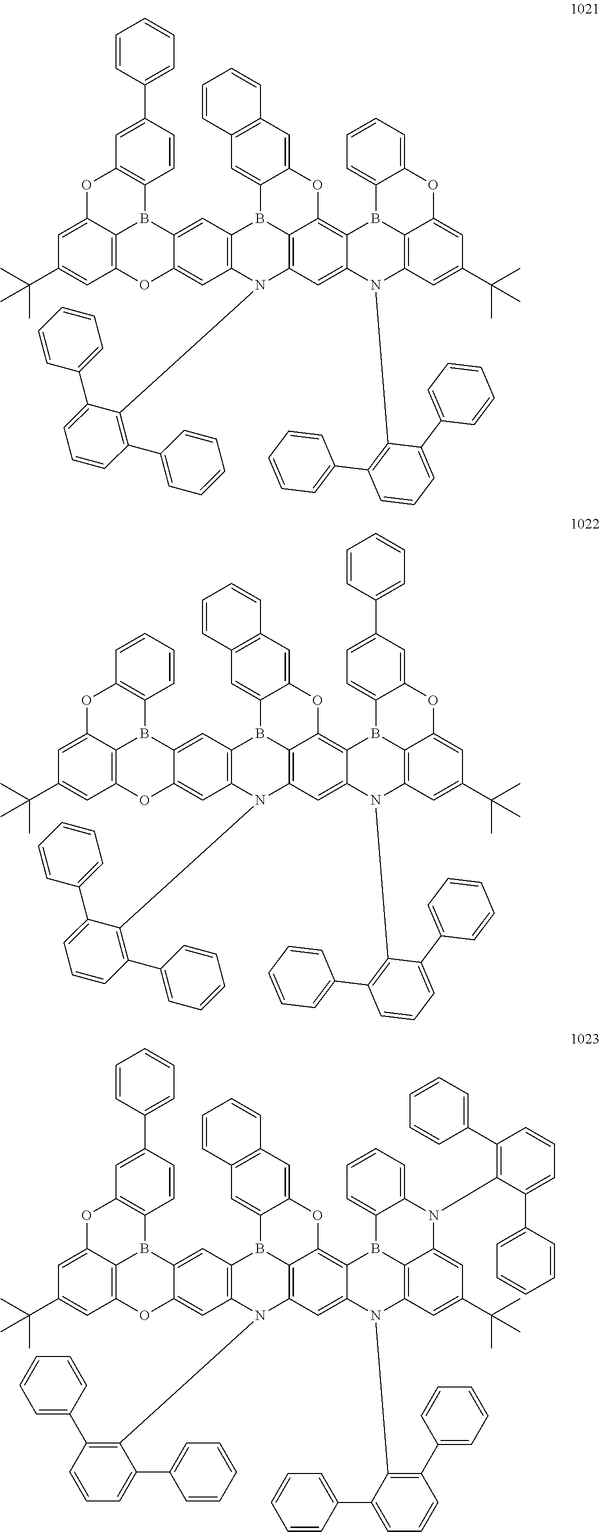 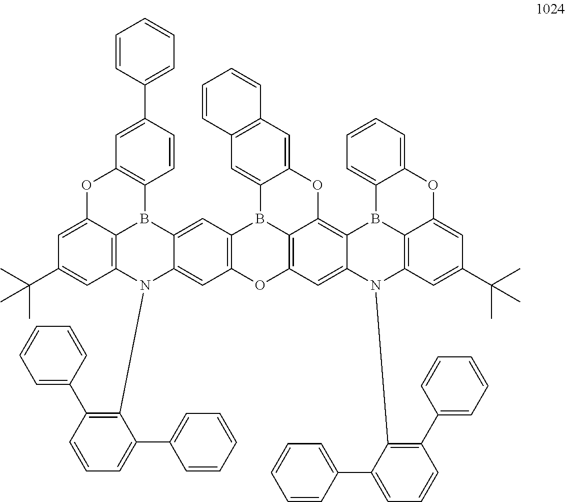 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2cc3ccccc3cc2Oc2c1c(cc1c2B2c3ccccc3Oc3cc(C(C)(C)C)cc(c32)N1c1c(-c2ccccc2)cccc1-c1ccccc1)O4] 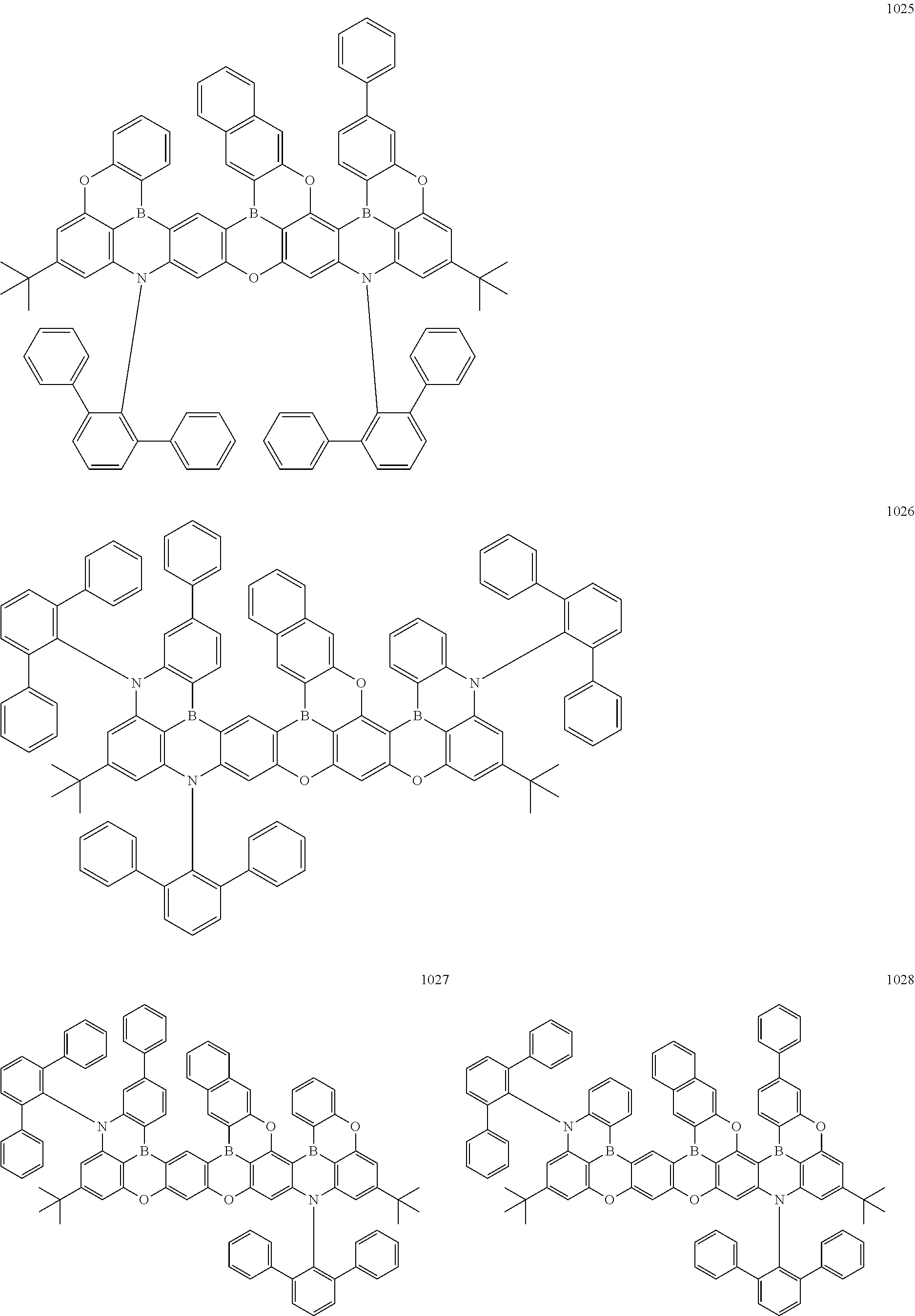 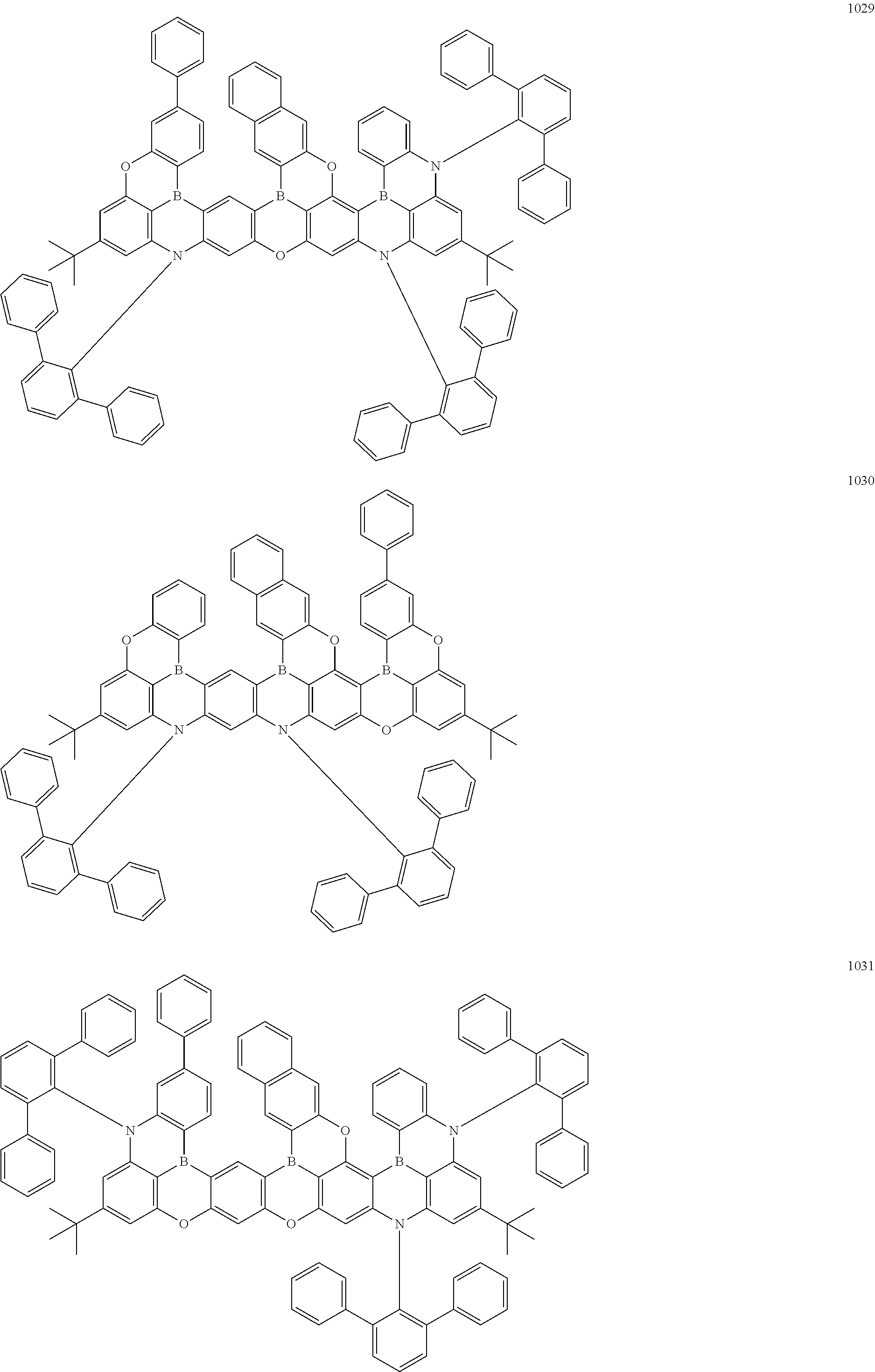 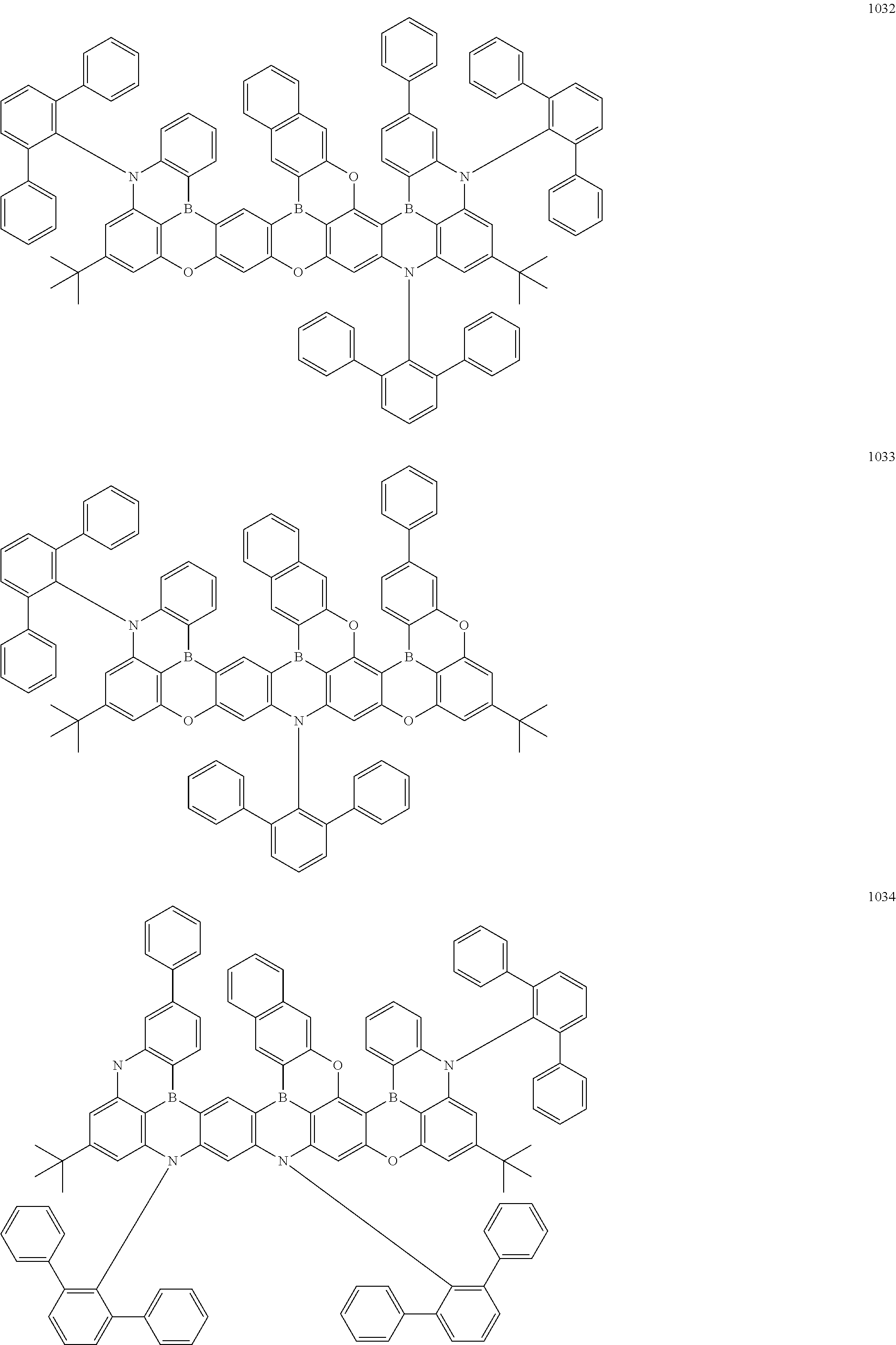 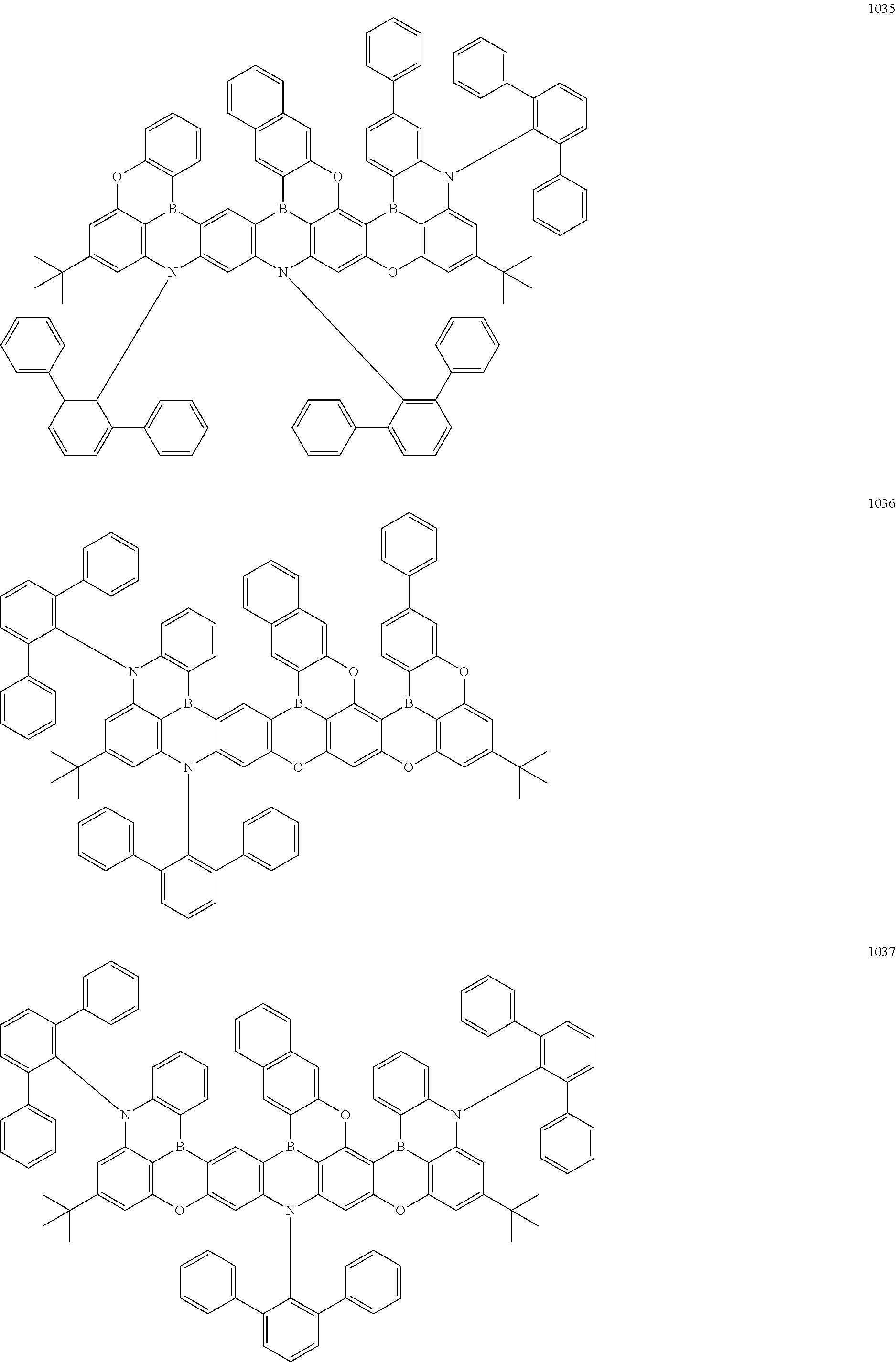 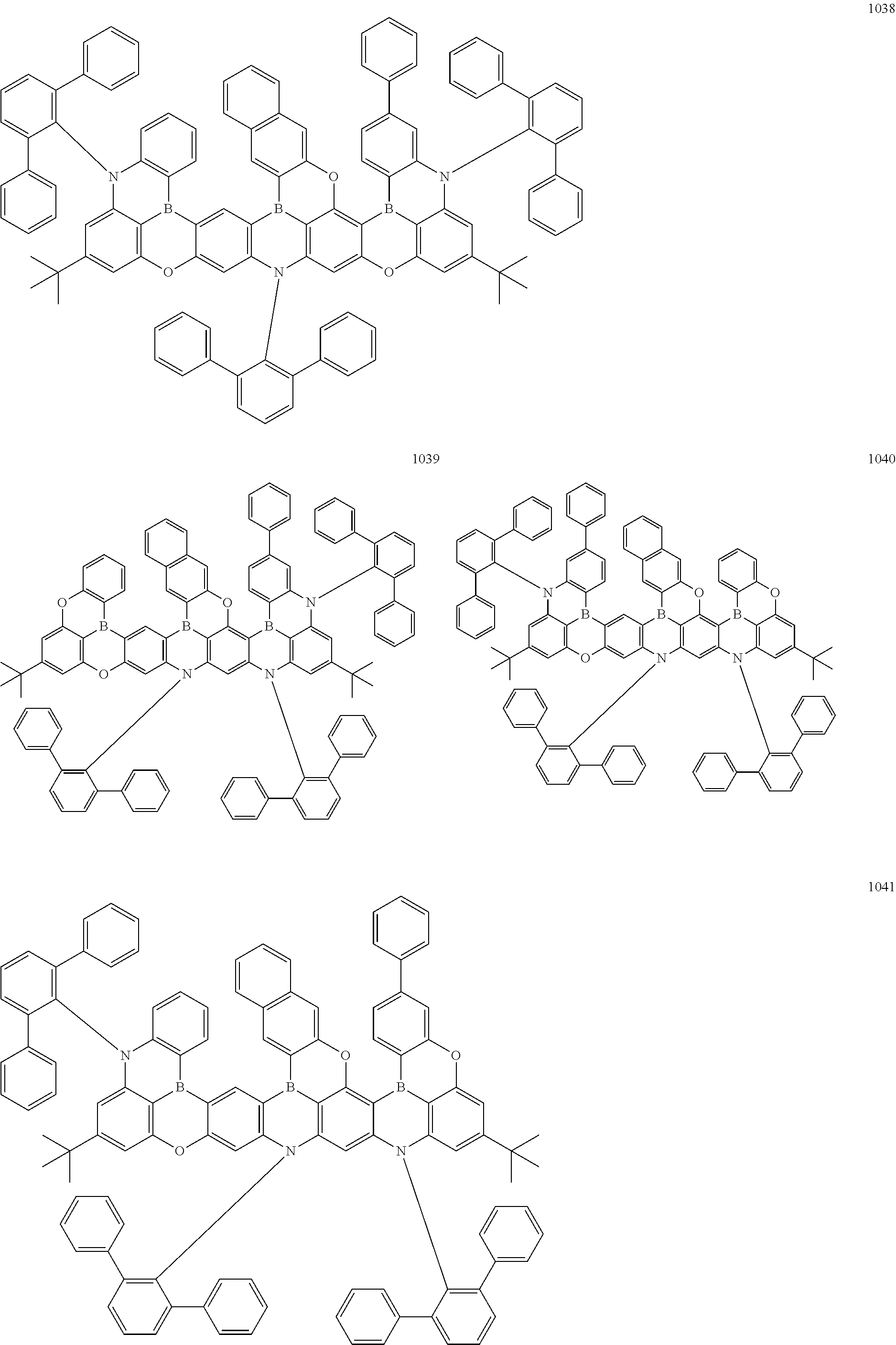 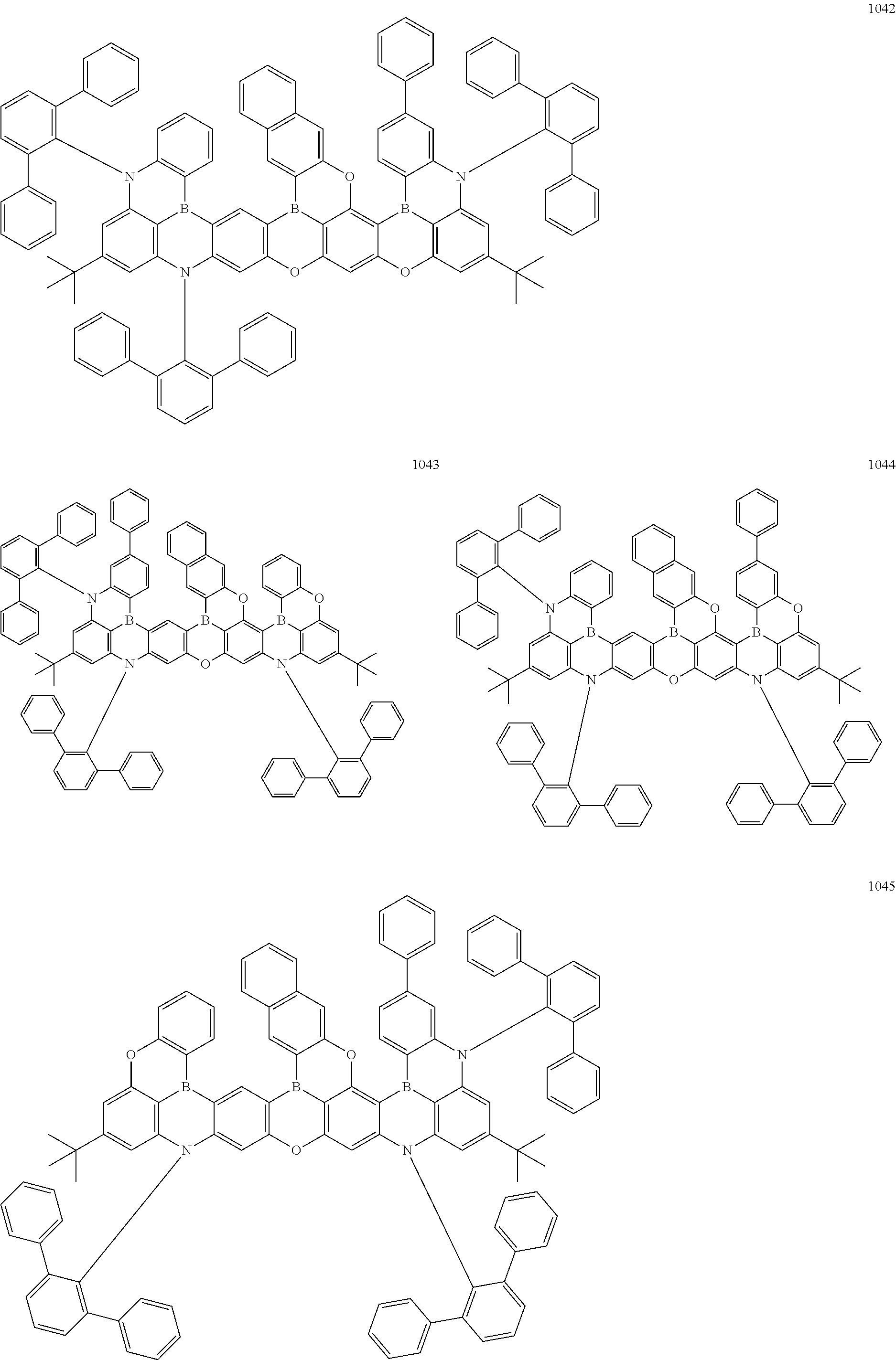 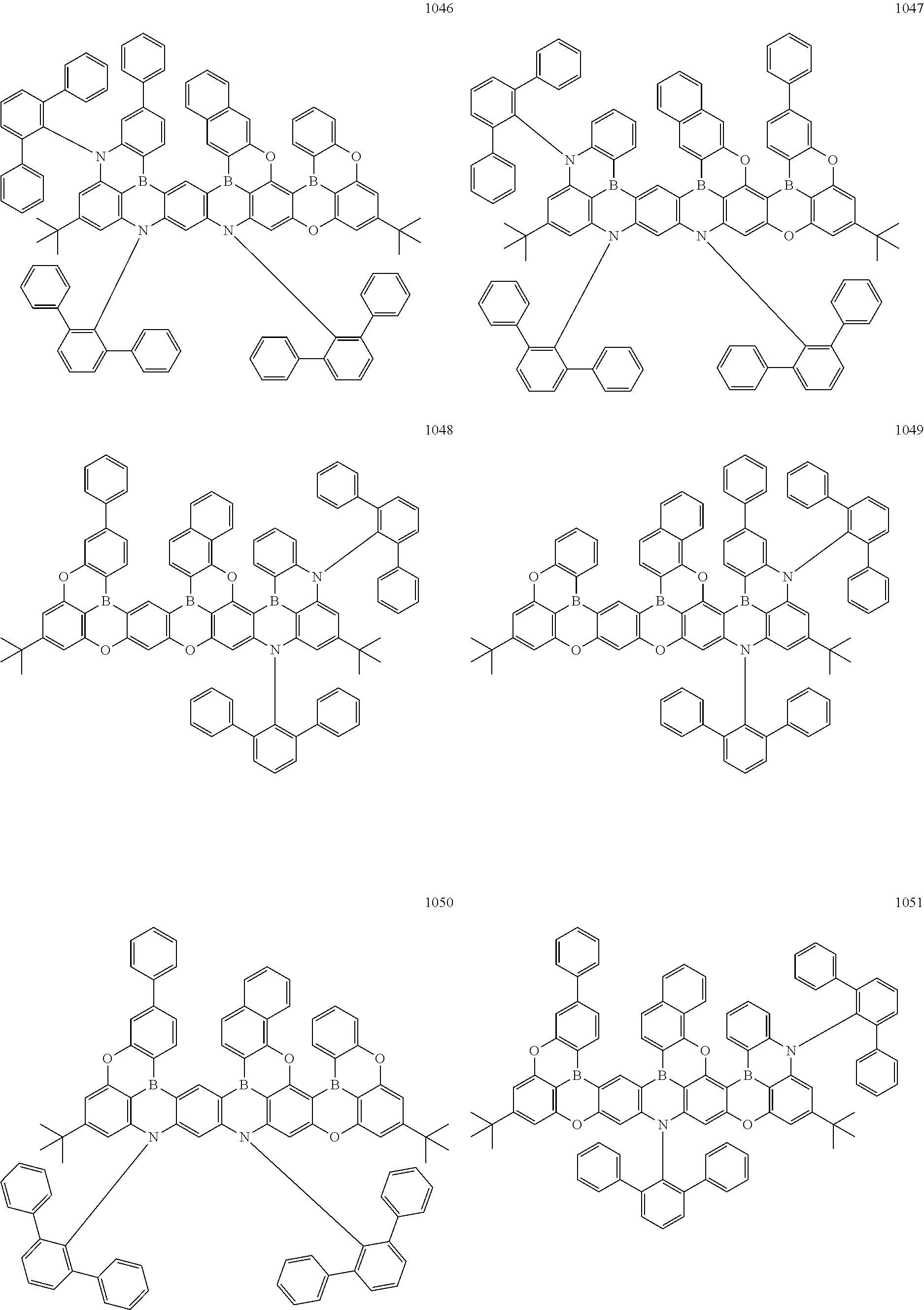 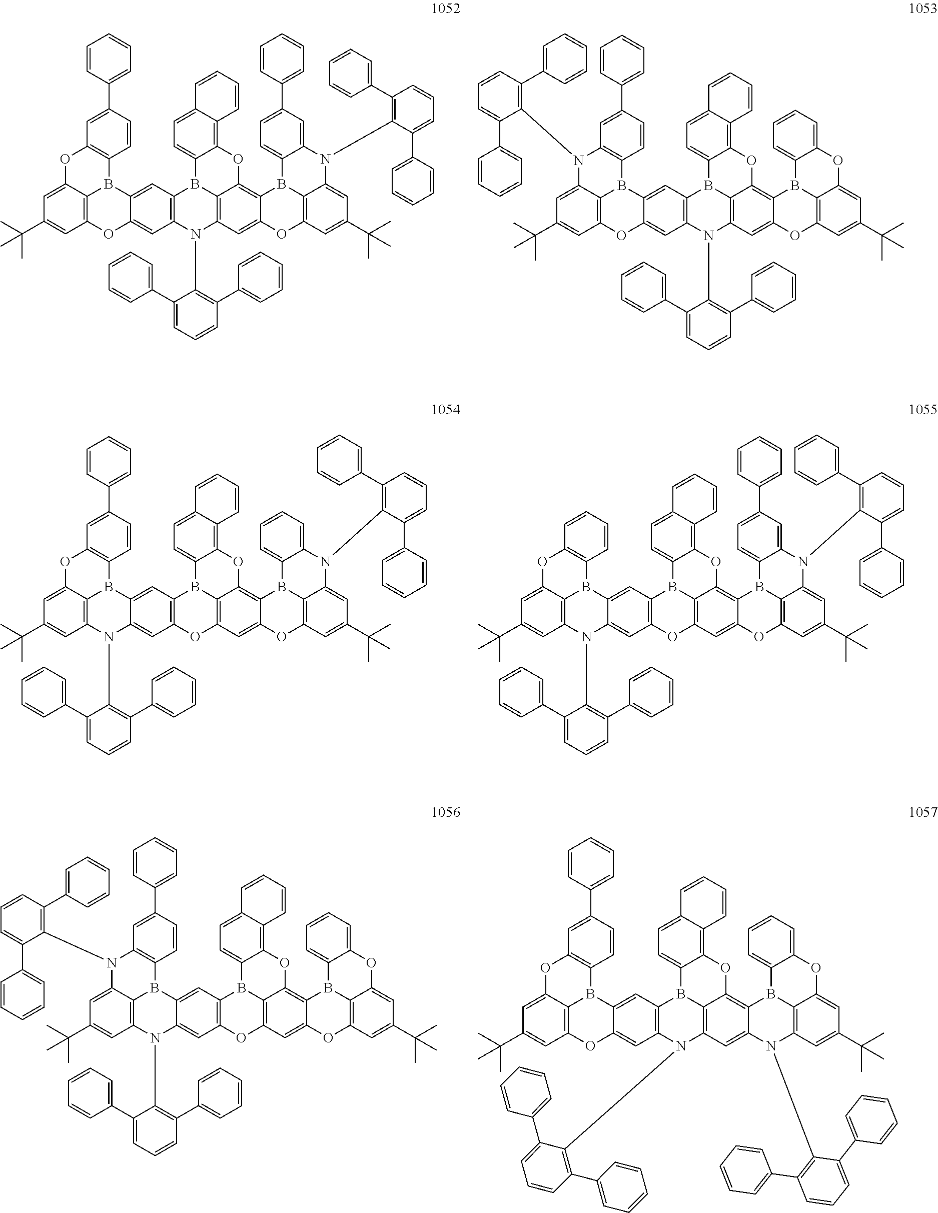 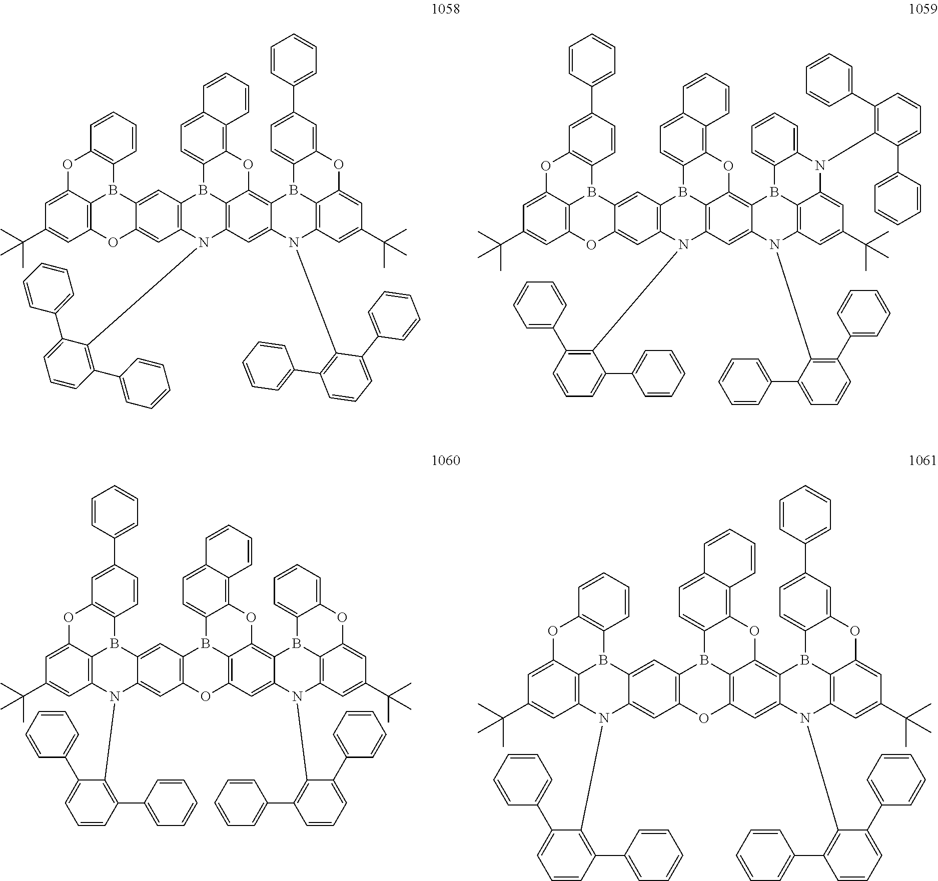 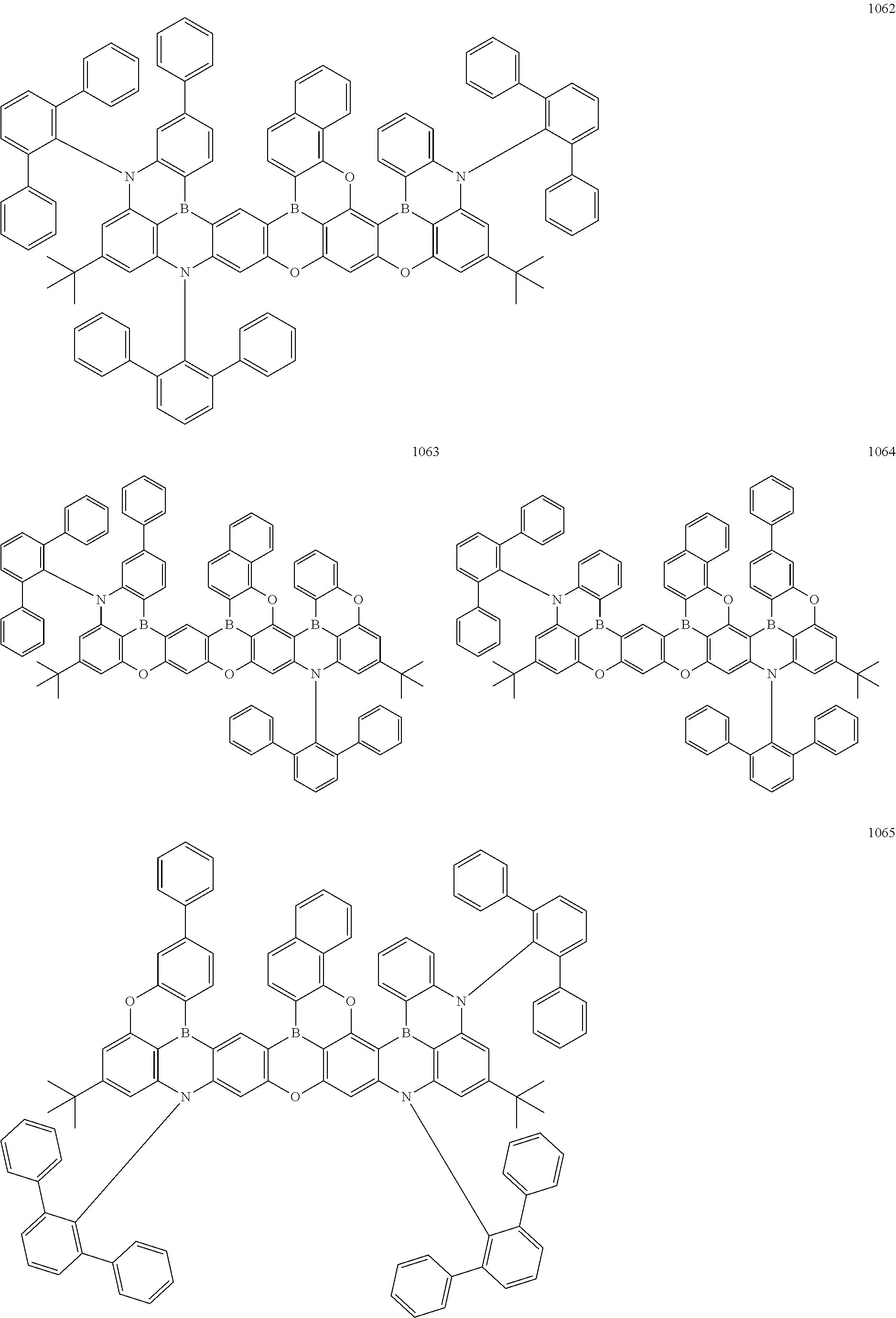 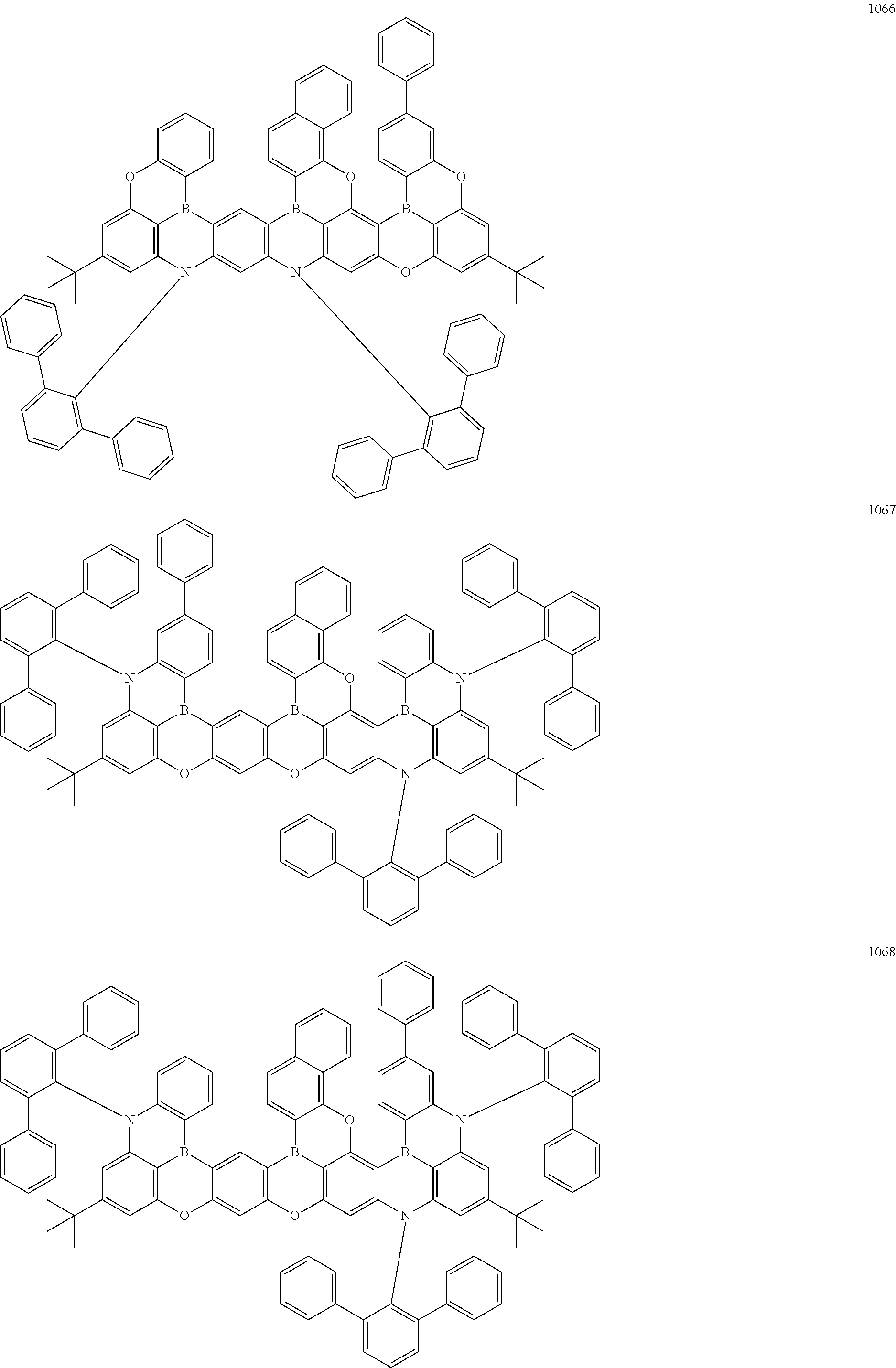 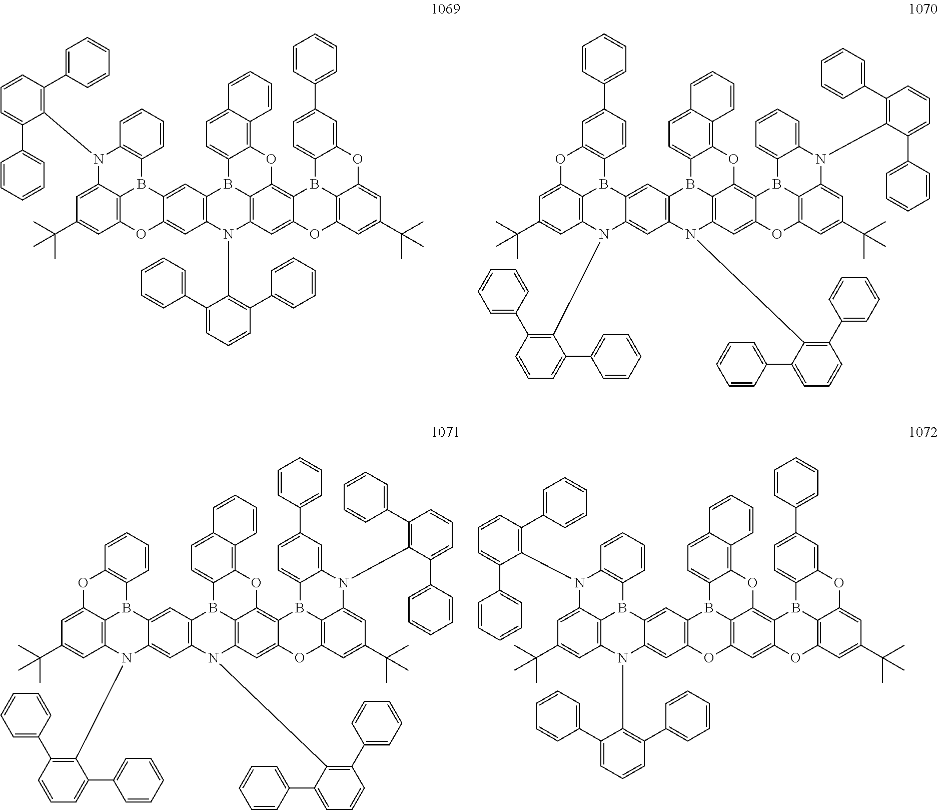 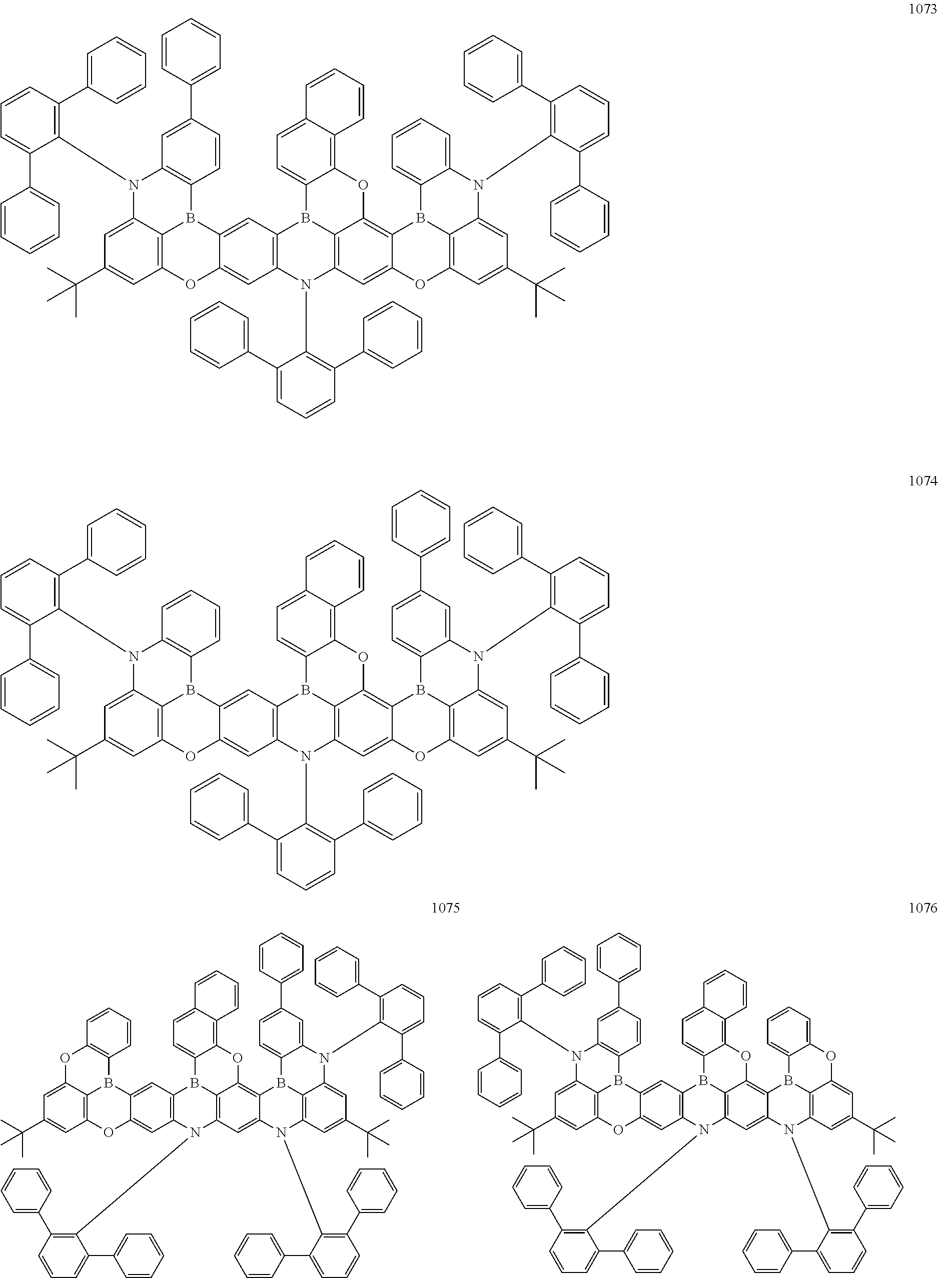 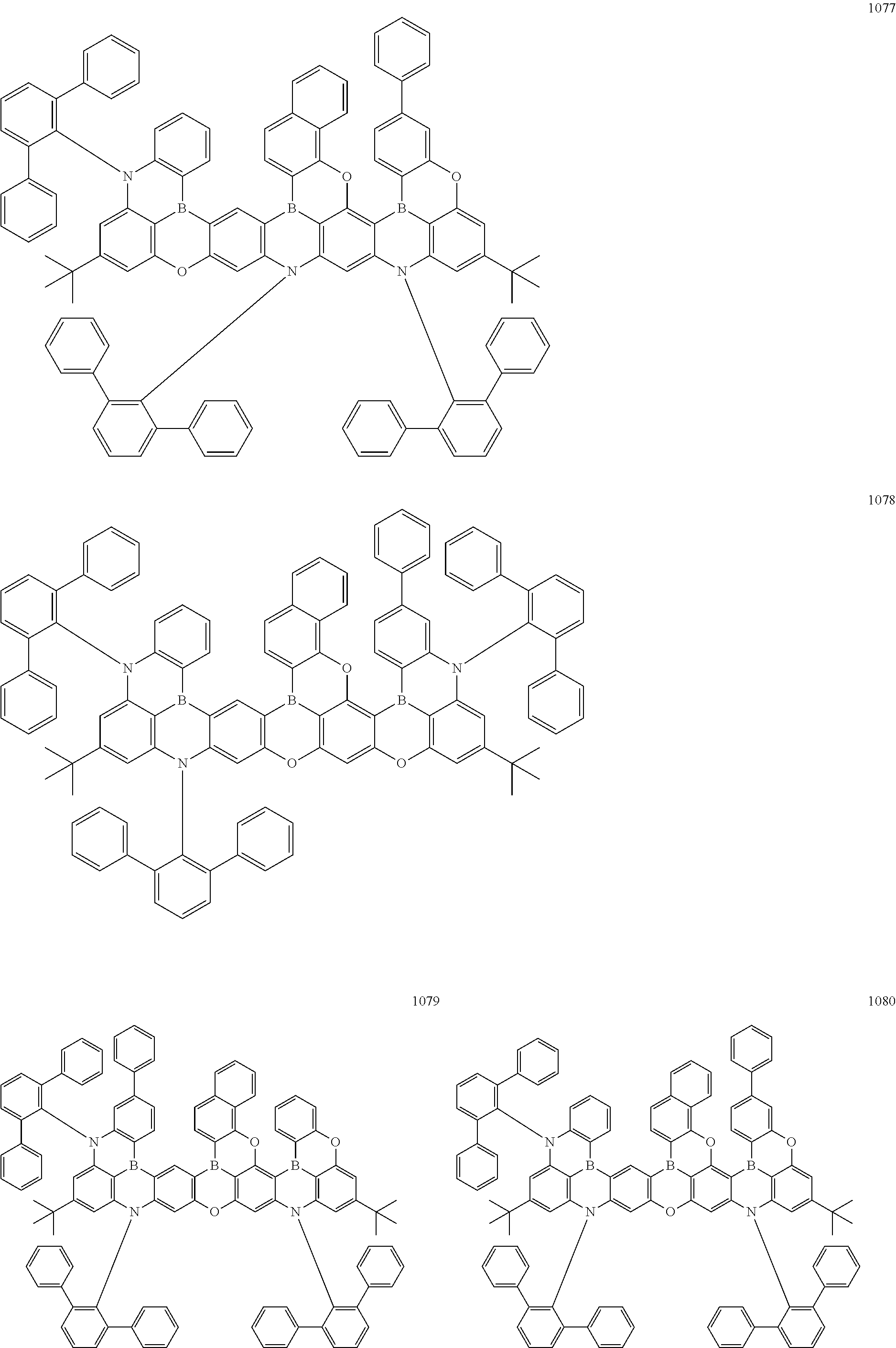 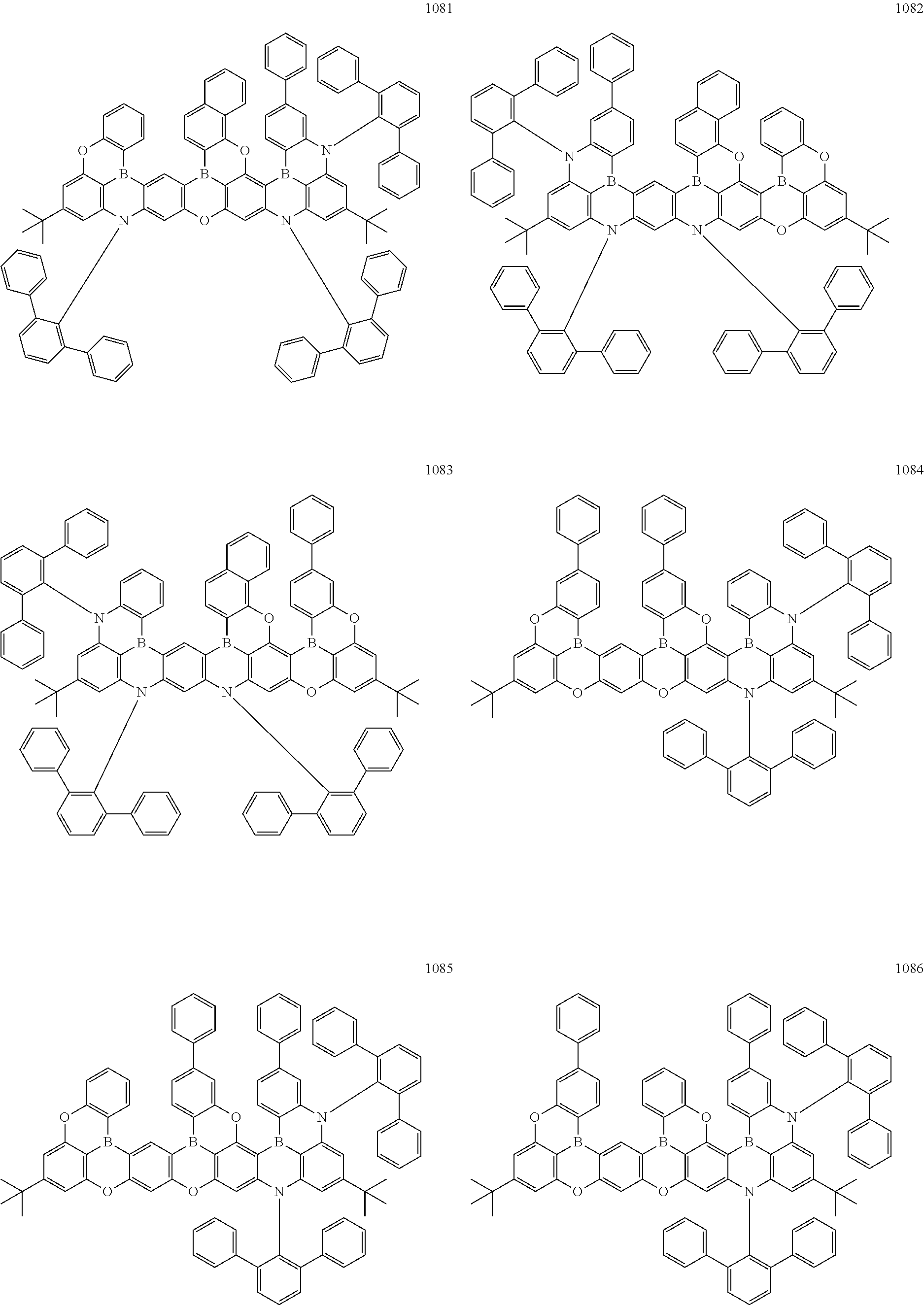 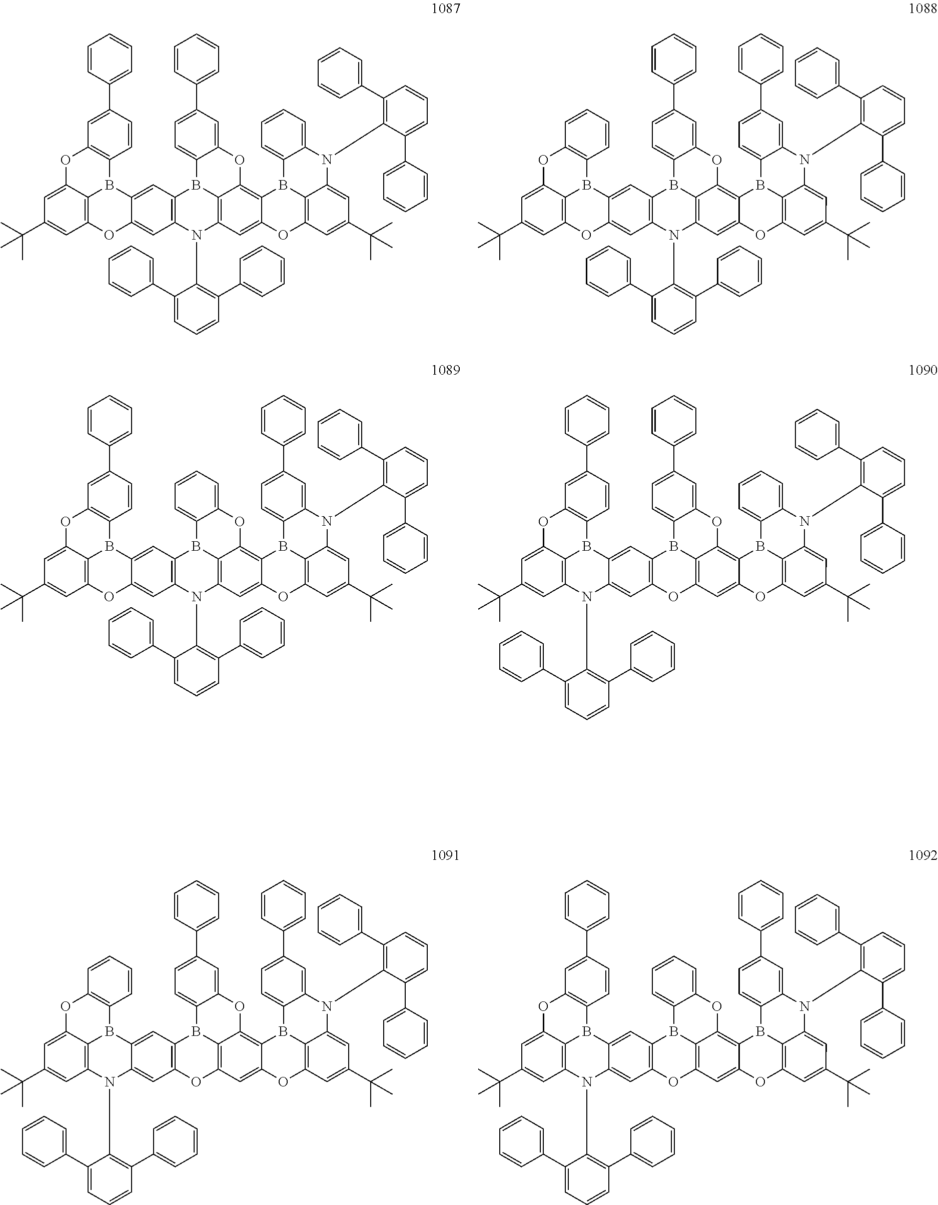 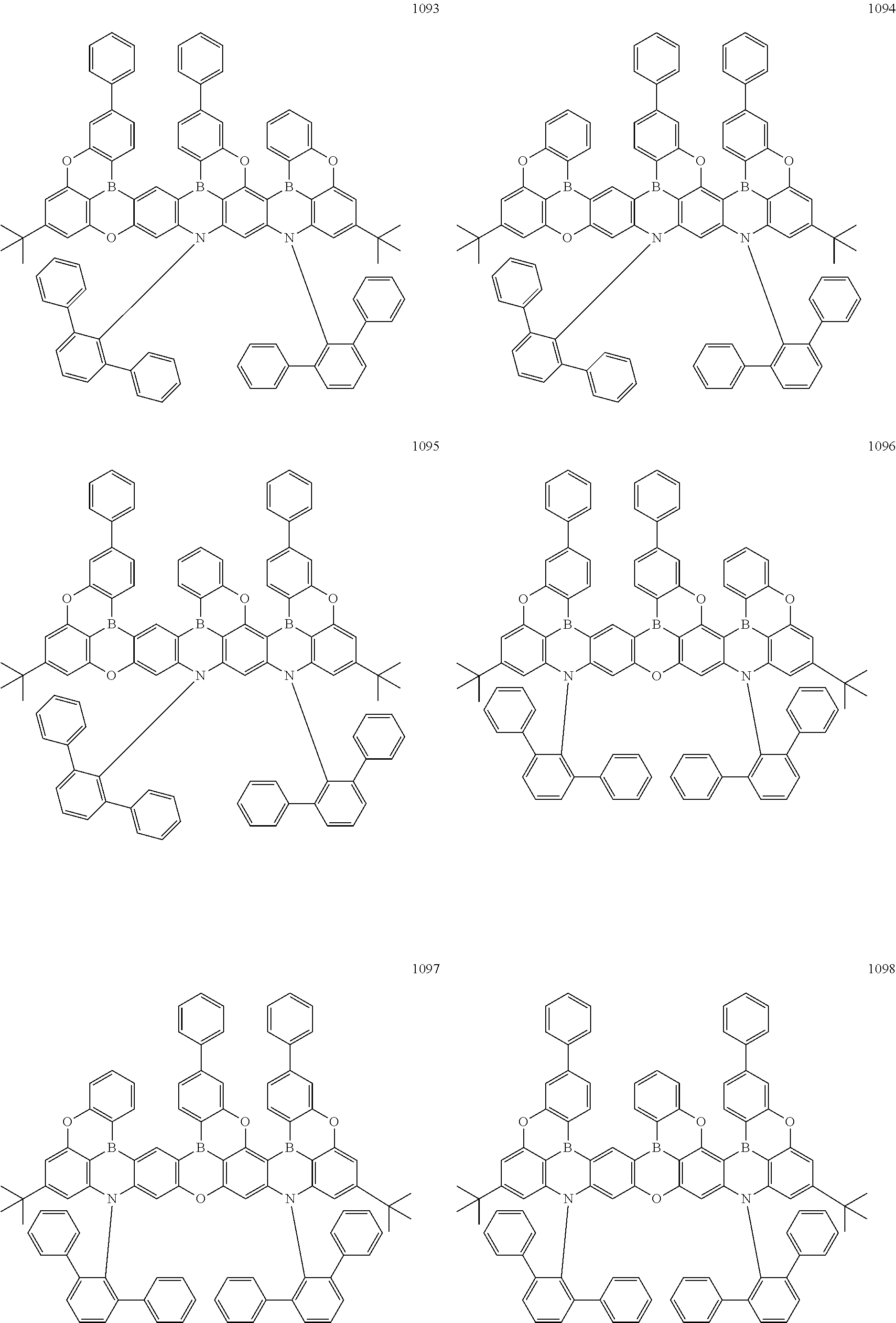 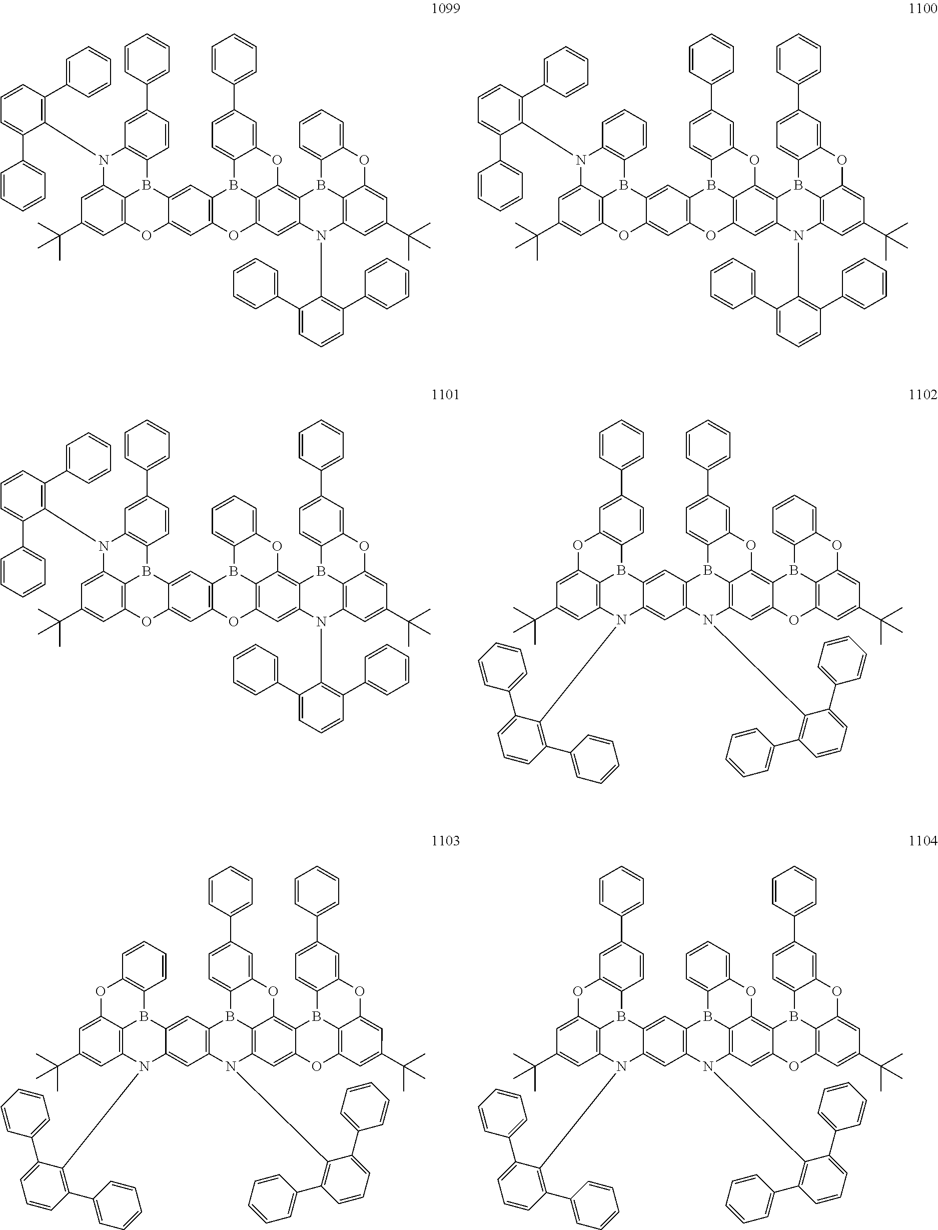 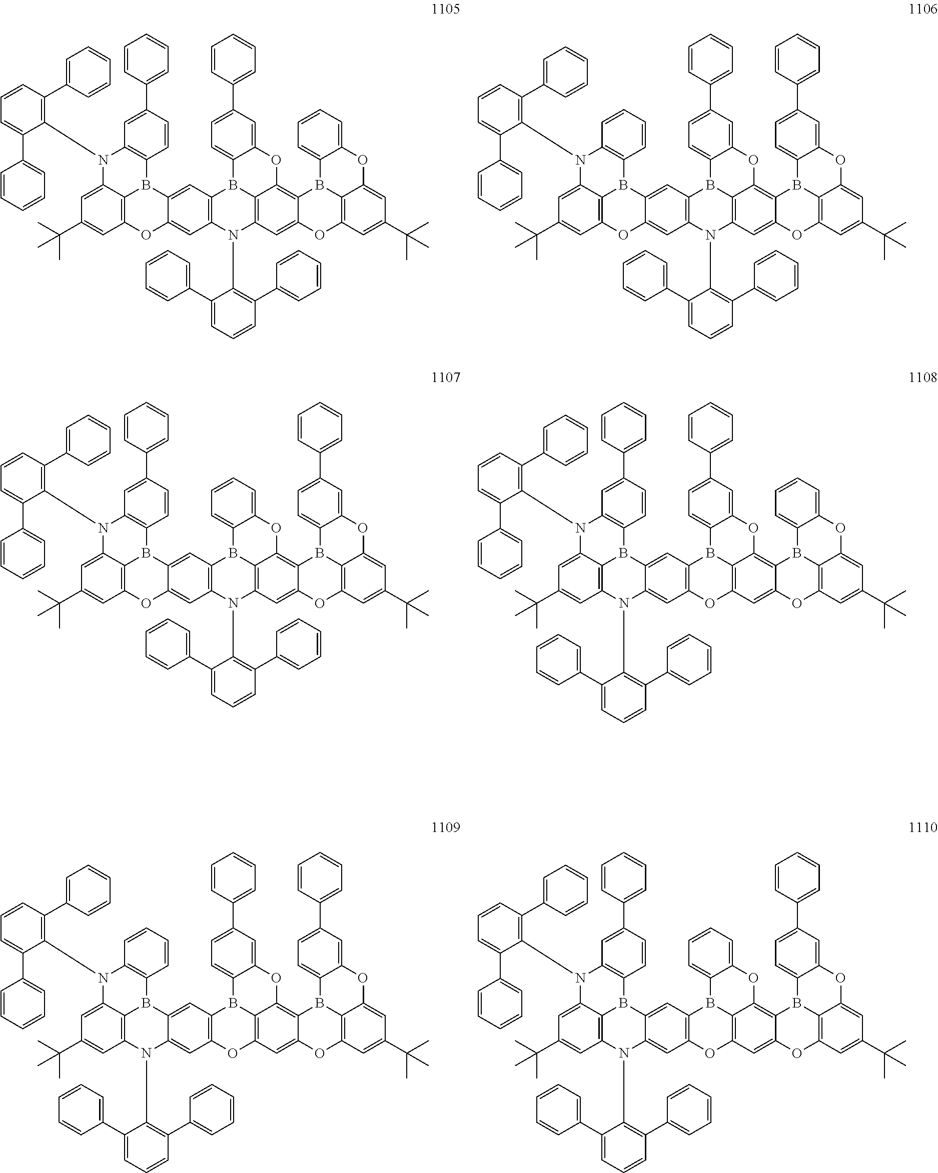 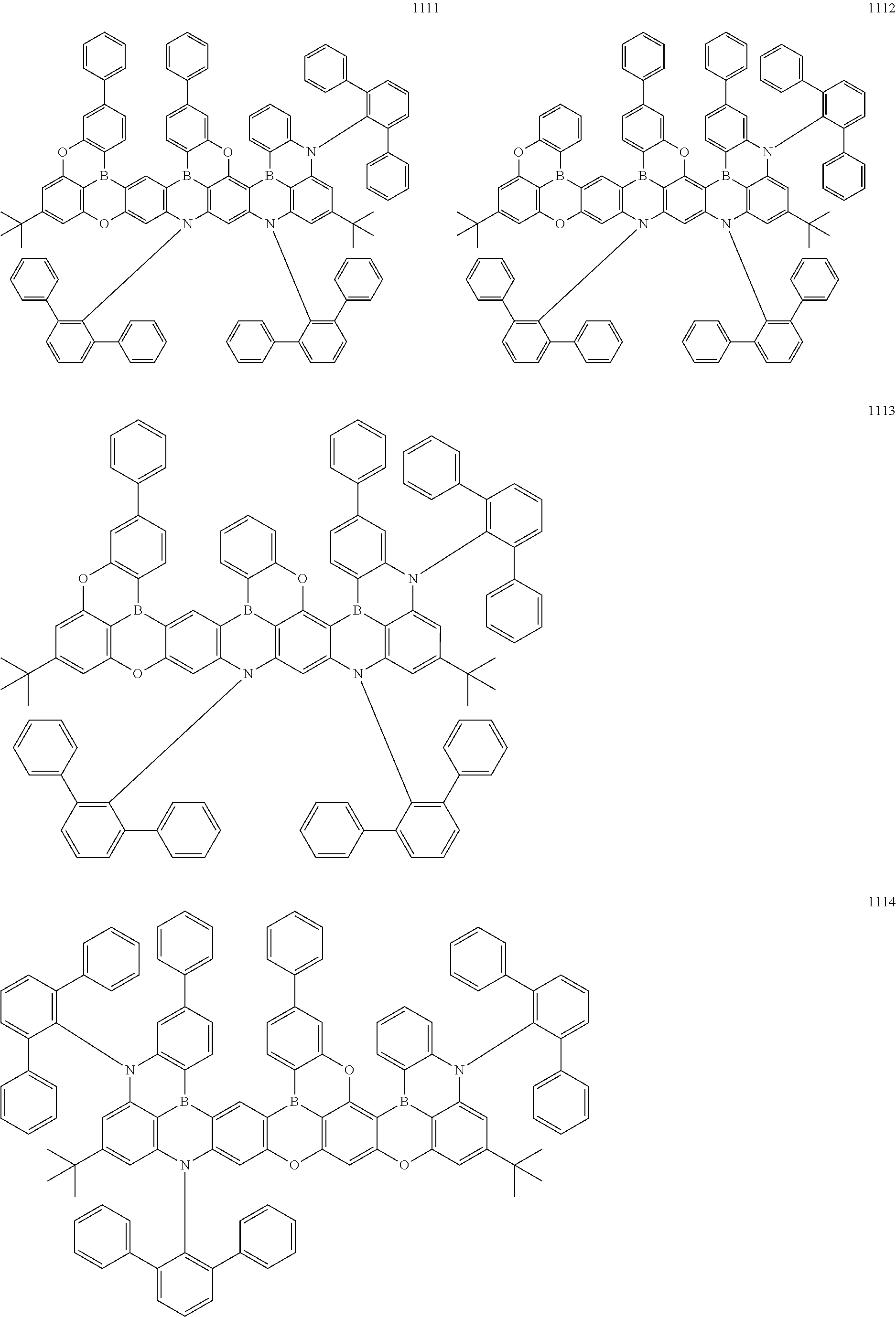 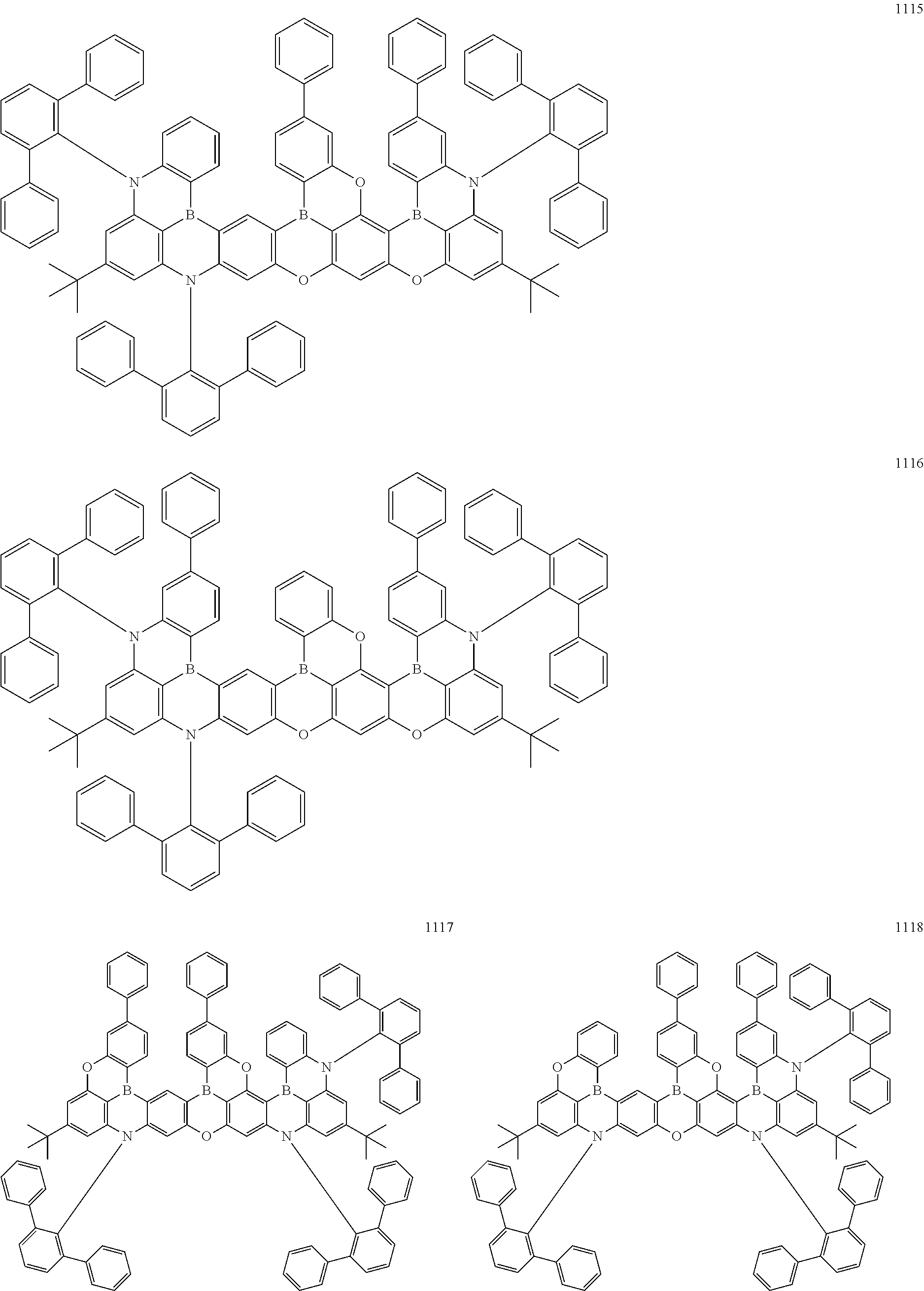 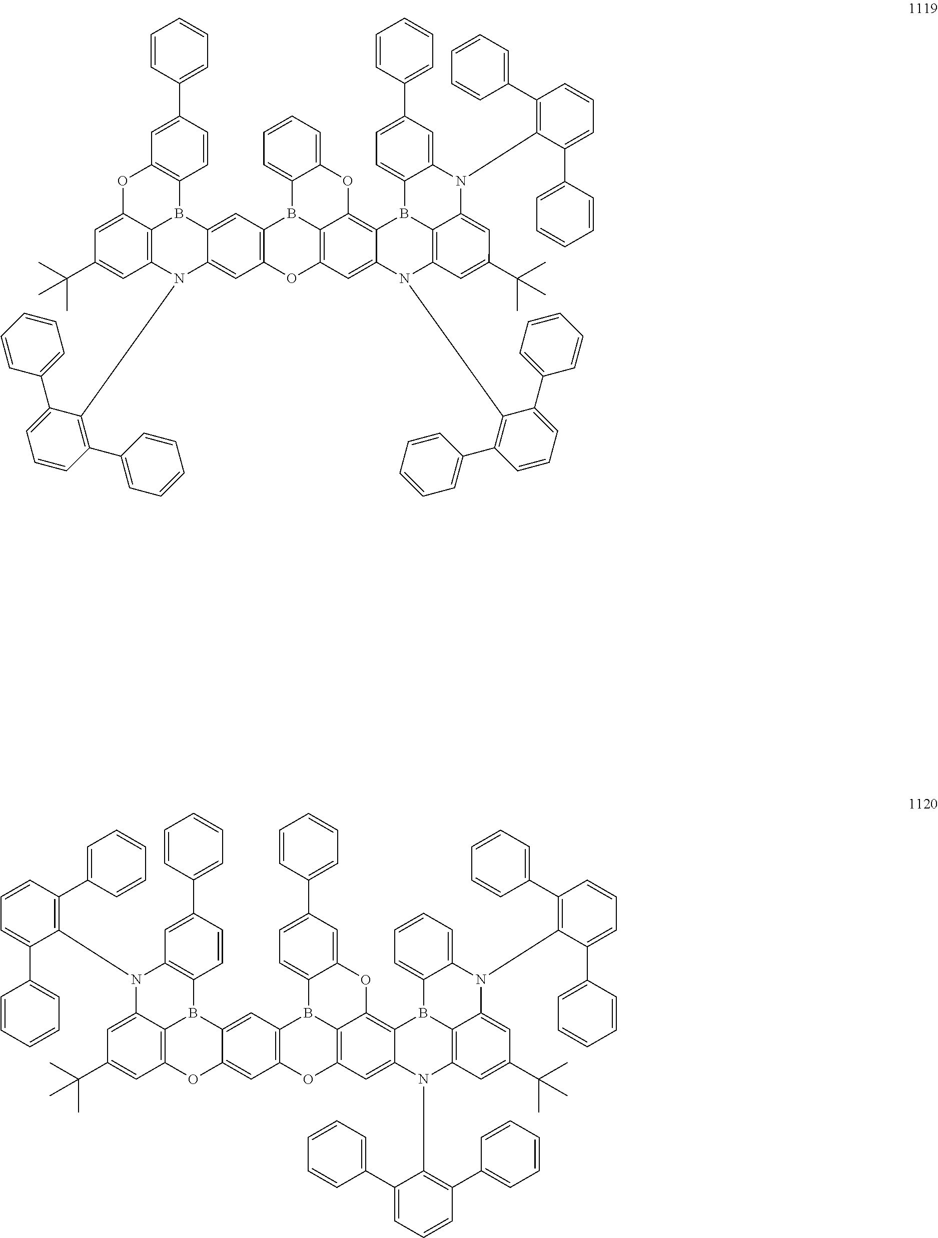 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)N1c1c(-c2ccccc2)cccc1-c1ccccc1)O4 ; CC(C)(C)c1cc2c3c(c1)N(c1c(-c4ccccc4)cccc1-c1ccccc1)c1cc(-c4ccccc4)ccc1B3c1cc3c(cc1O2)Oc1cc2c(c4c1B3c1ccc(-c3ccccc3)cc1O4)B1c3ccccc3N(c3c(-c4ccccc4)cccc3-c3ccccc3)c3cc(C(C)(C)C)cc(c31)N2c1c(-c2ccccc2)cccc1-c1ccccc1] 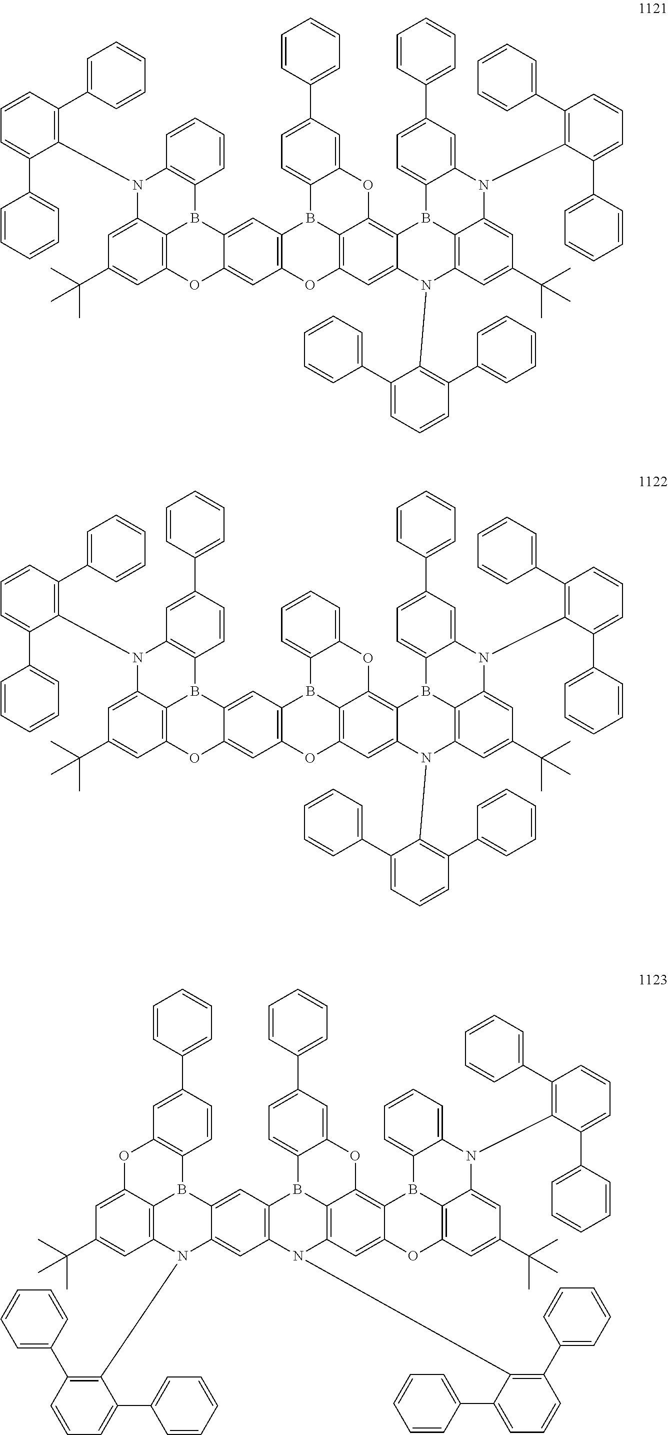 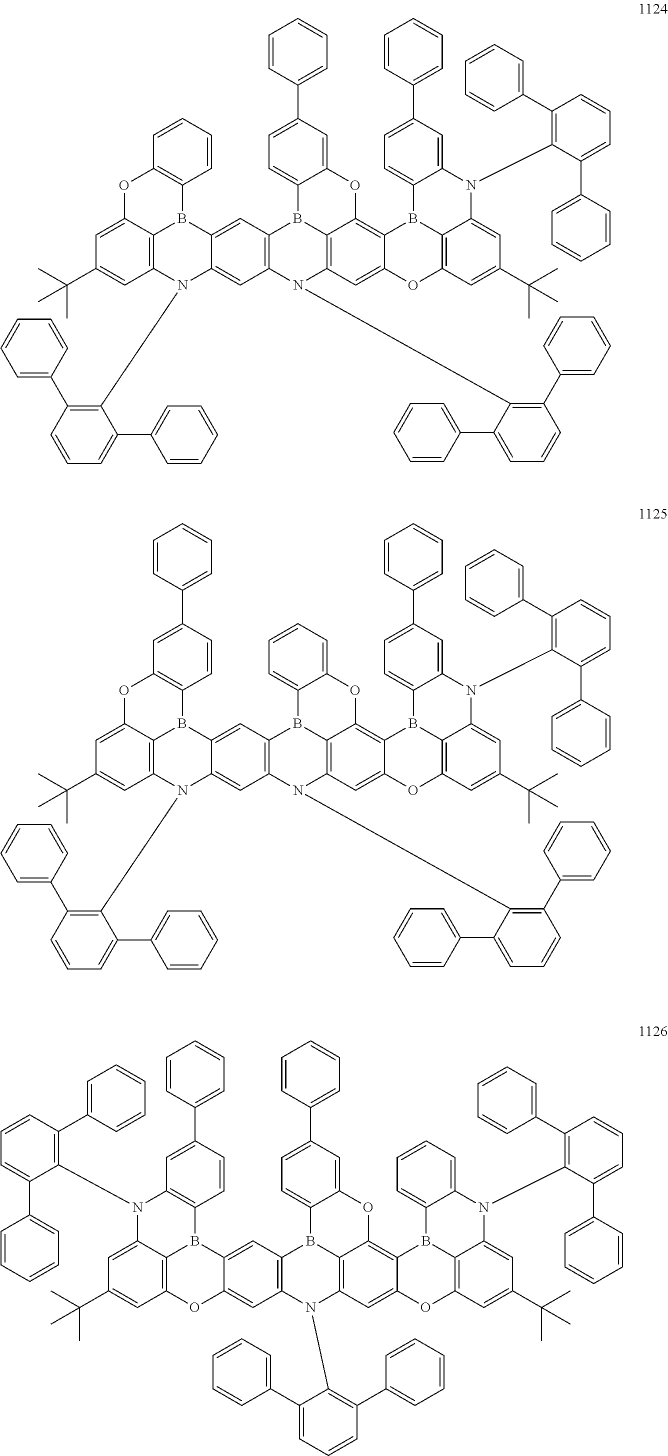 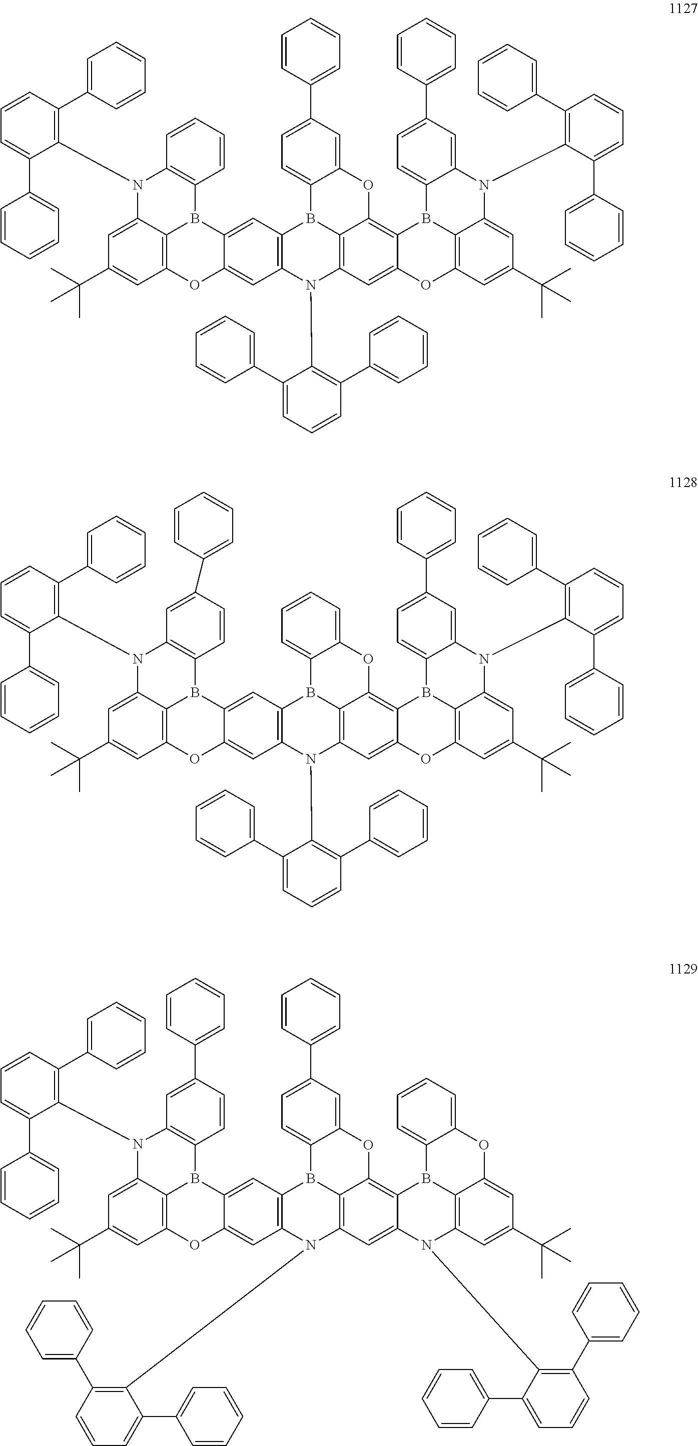 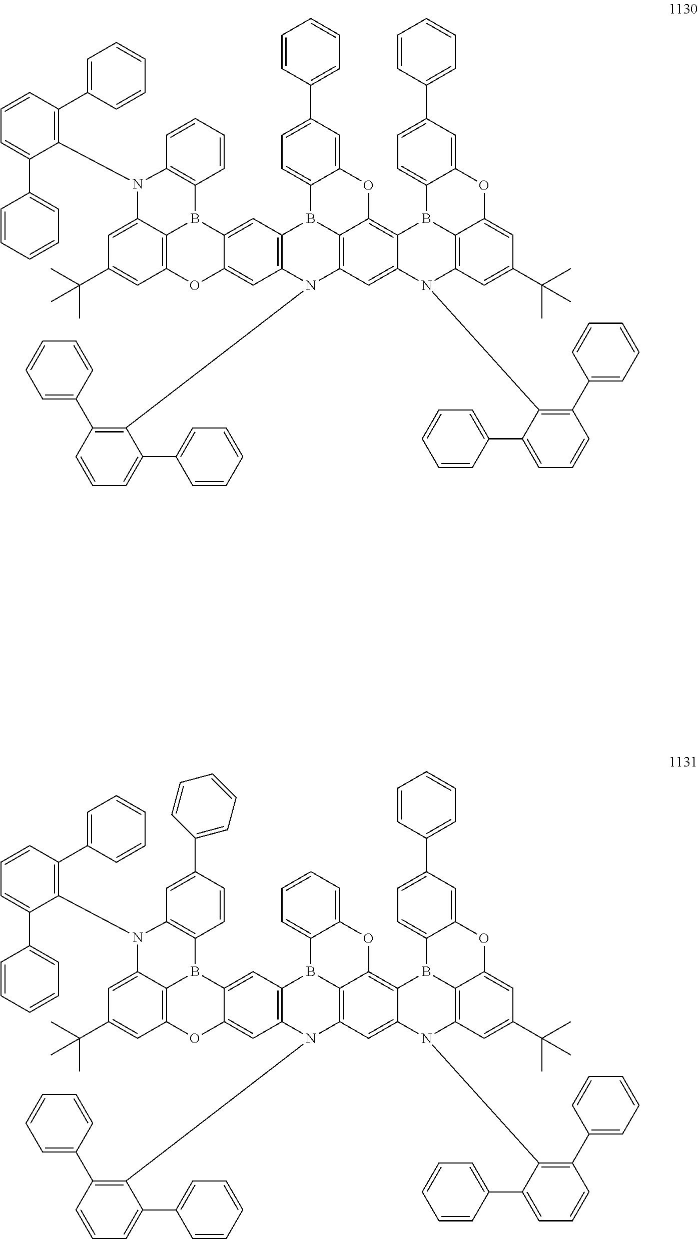 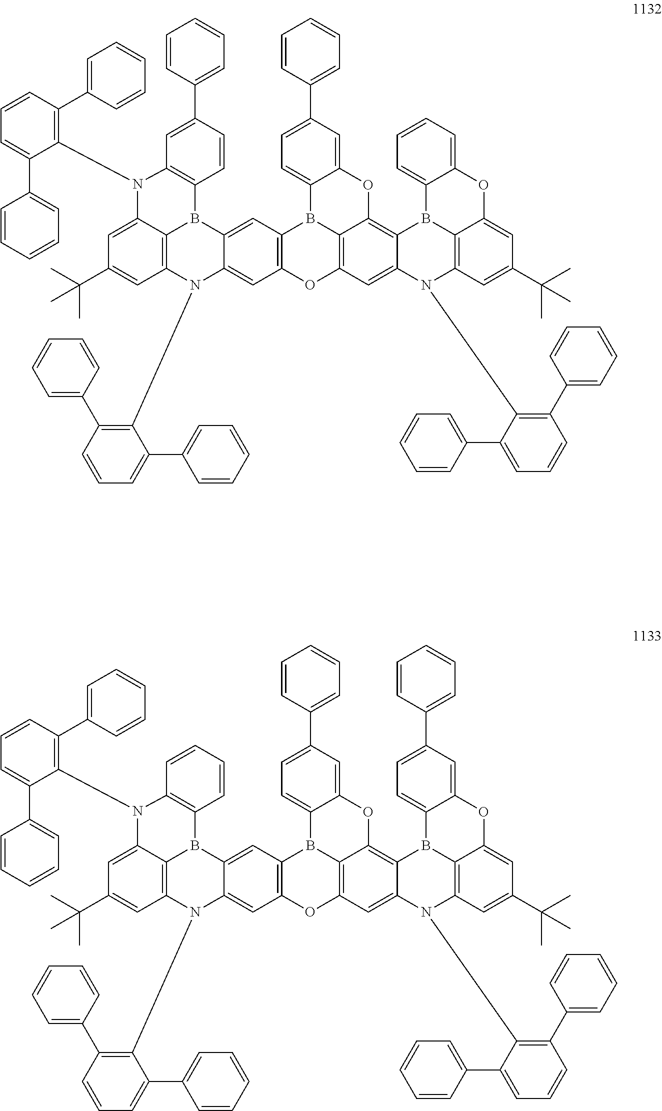 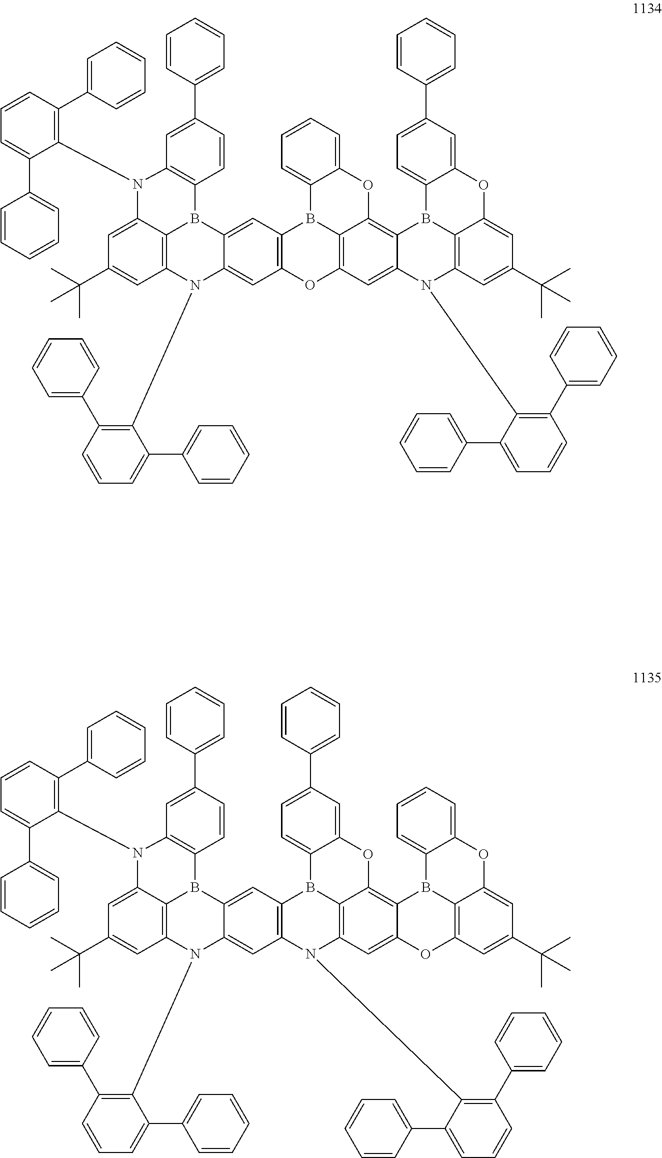 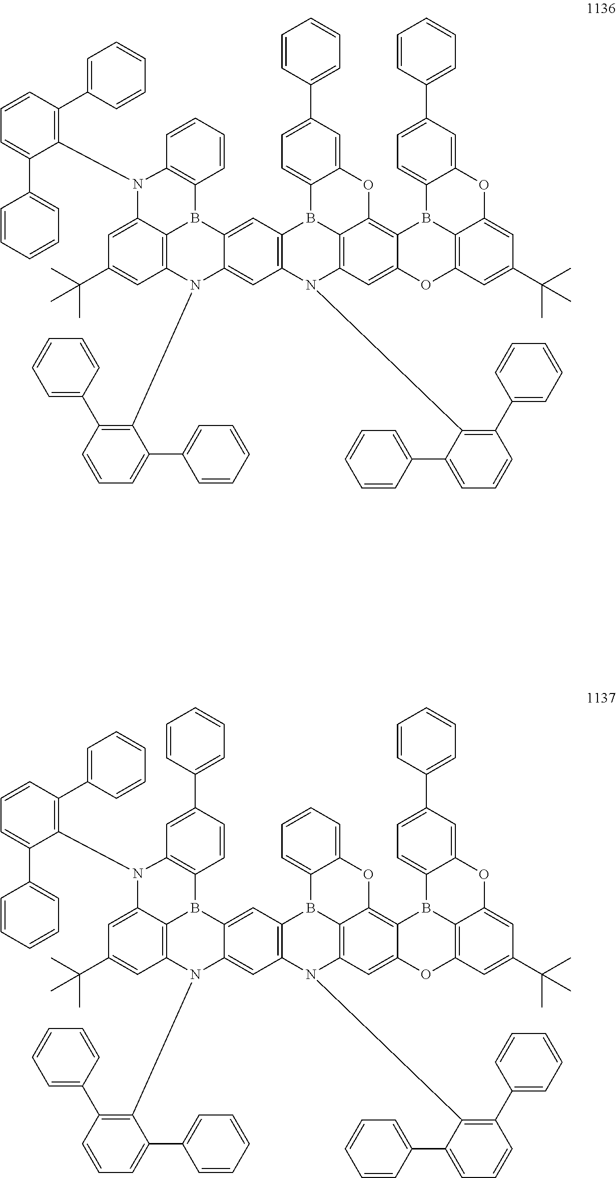 [SMILES: CC(C)(C)c1cc2c3c(c1)Oc1cc4c5c(c1B3c1ccc(-c3ccccc3)cc1O2)Oc1cc(-c2ccccc2)ccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccccc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1c(-c3ccccc3)cccc1-c1ccccc1)N(c1c(-c3ccccc3)cccc1-c1ccccc1)c1cc(C(C)(C)C)cc3c1B2c1ccc(-c2ccccc2)cc1N3c1c(-c2ccccc2)cccc1-c1ccccc1] 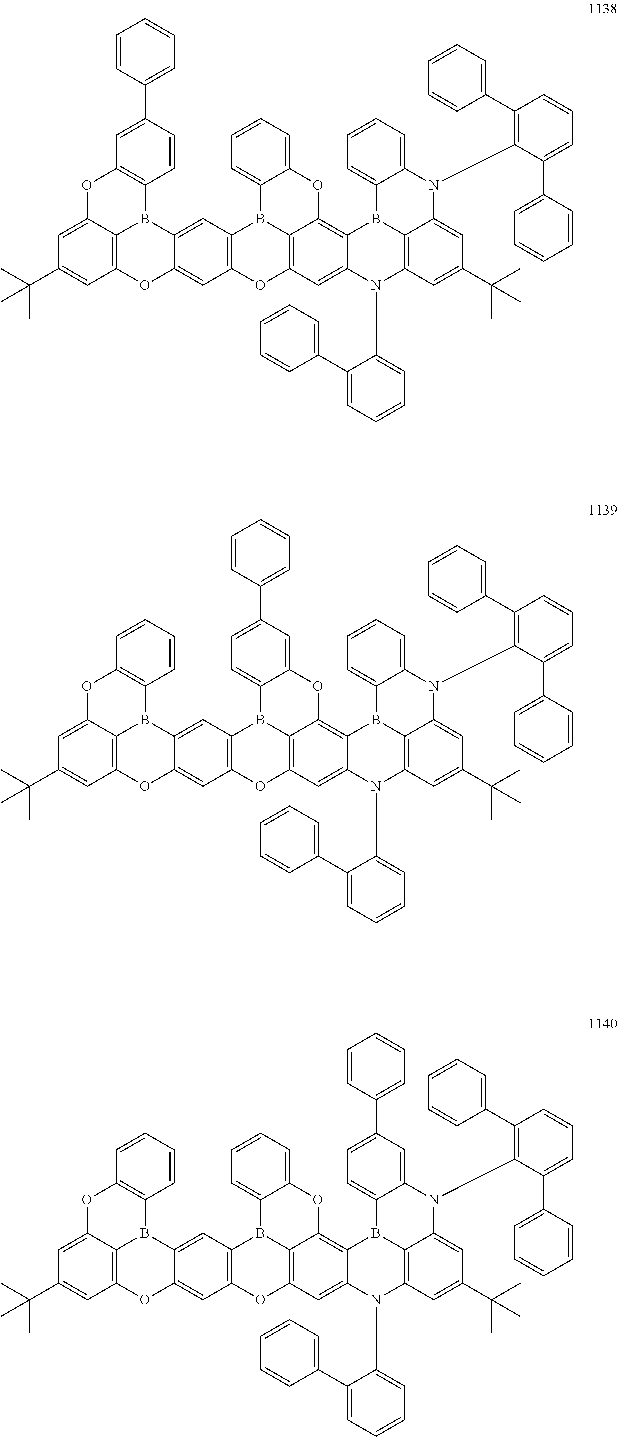 [SMILES: CC(C)(C)c1cc2c3c(c1)Oc1cc4c(cc1B3c1ccc(-c3ccccc3)cc1O2)B1c2ccccc2Oc2c1c(cc1c2B2c3ccccc3N(c3c(-c5ccccc5)cccc3-c3ccccc3)c3cc(C(C)(C)C)cc(c32)N1c1ccccc1-c1ccccc1)O4 ; CC(C)(C)c1cc2c3c(c1)Oc1cc4c(cc1B3c1ccccc1O2)B1c2ccc(-c3ccccc3)cc2Oc2c1c(cc1c2B2c3ccccc3N(c3c(-c5ccccc5)cccc3-c3ccccc3)c3cc(C(C)(C)C)cc(c32)N1c1ccccc1-c1ccccc1)O4 ; CC(C)(C)c1cc2c3c(c1)Oc1cc4c(cc1B3c1ccccc1O2)B1c2ccccc2Oc2c1c(cc1c2B2c3ccc(-c5ccccc5)cc3N(c3c(-c5ccccc5)cccc3-c3ccccc3)c3cc(C(C)(C)C)cc(c32)N1c1ccccc1-c1ccccc1)O4] 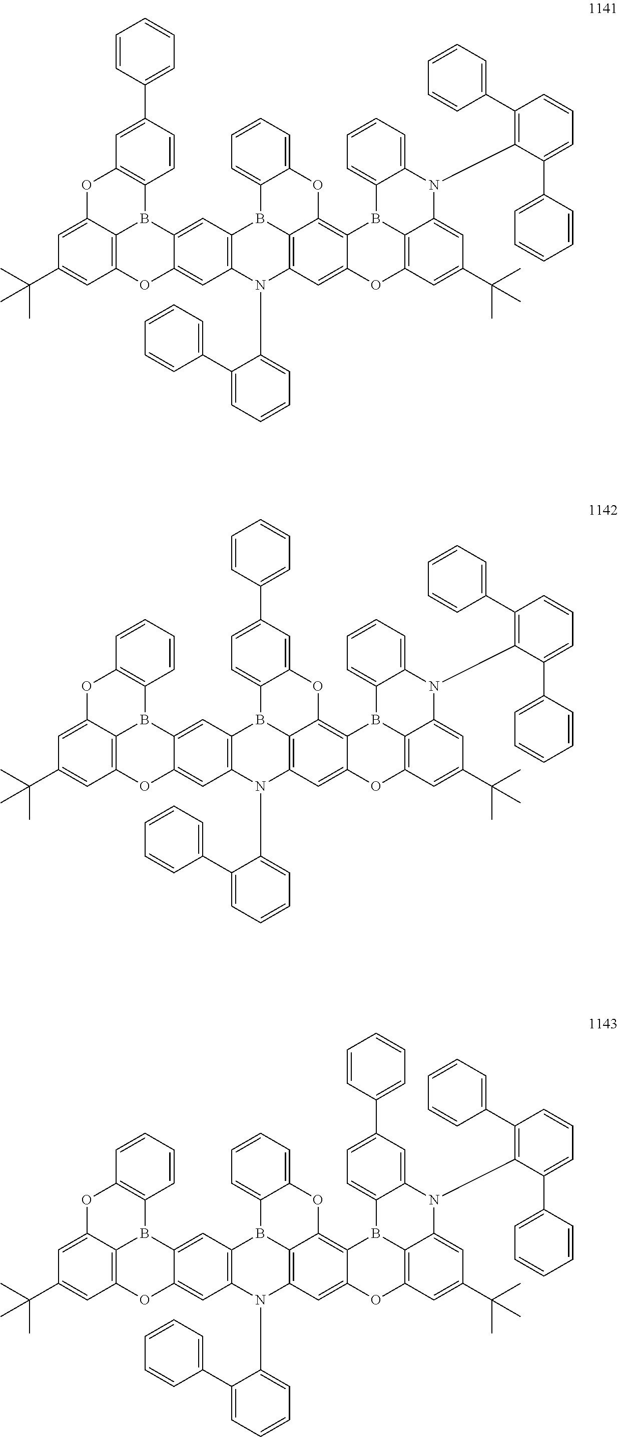 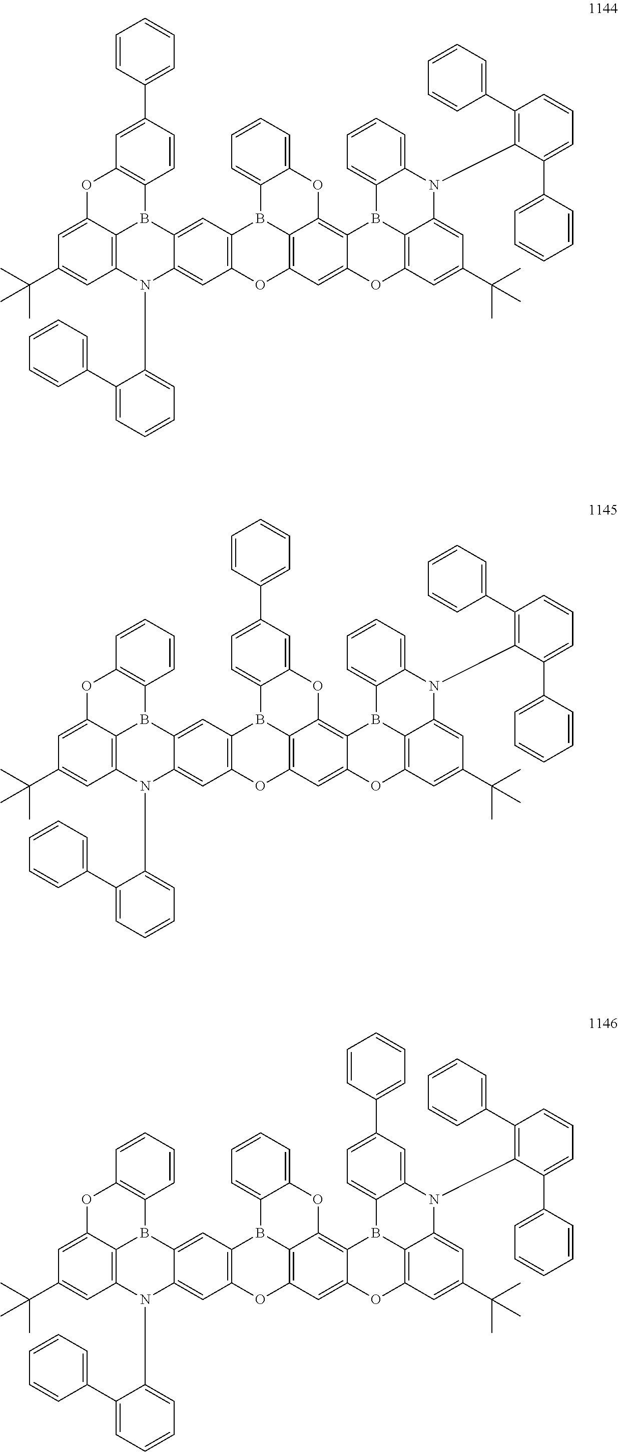 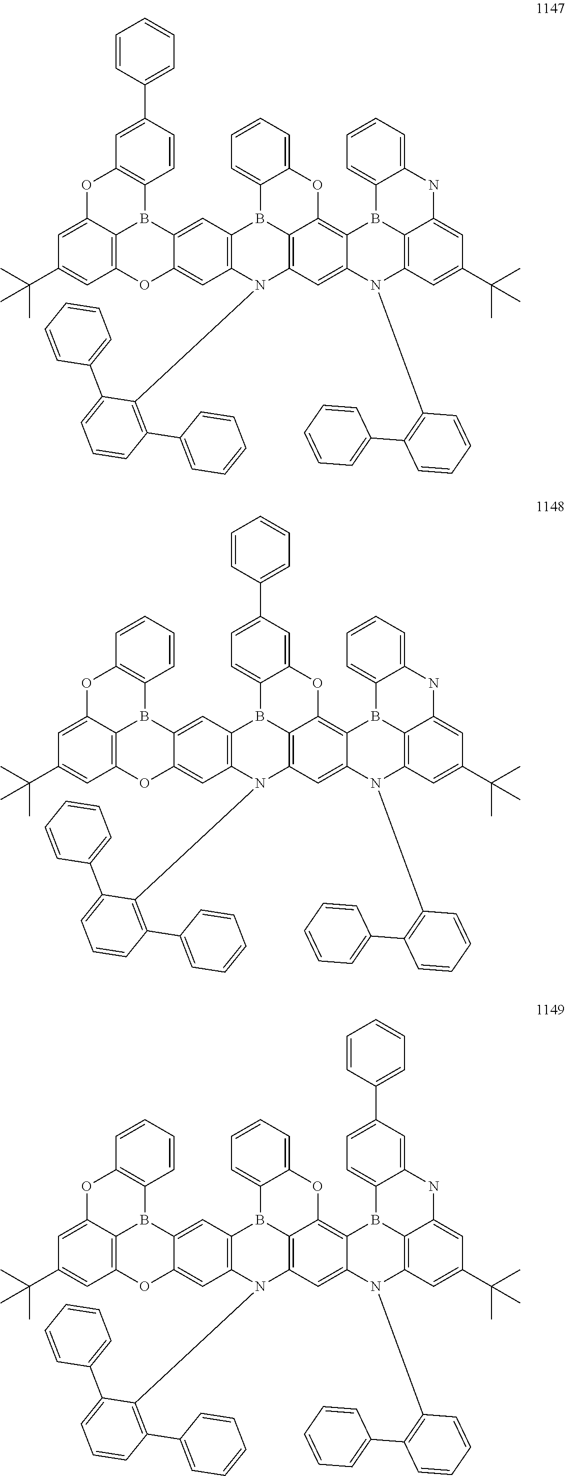 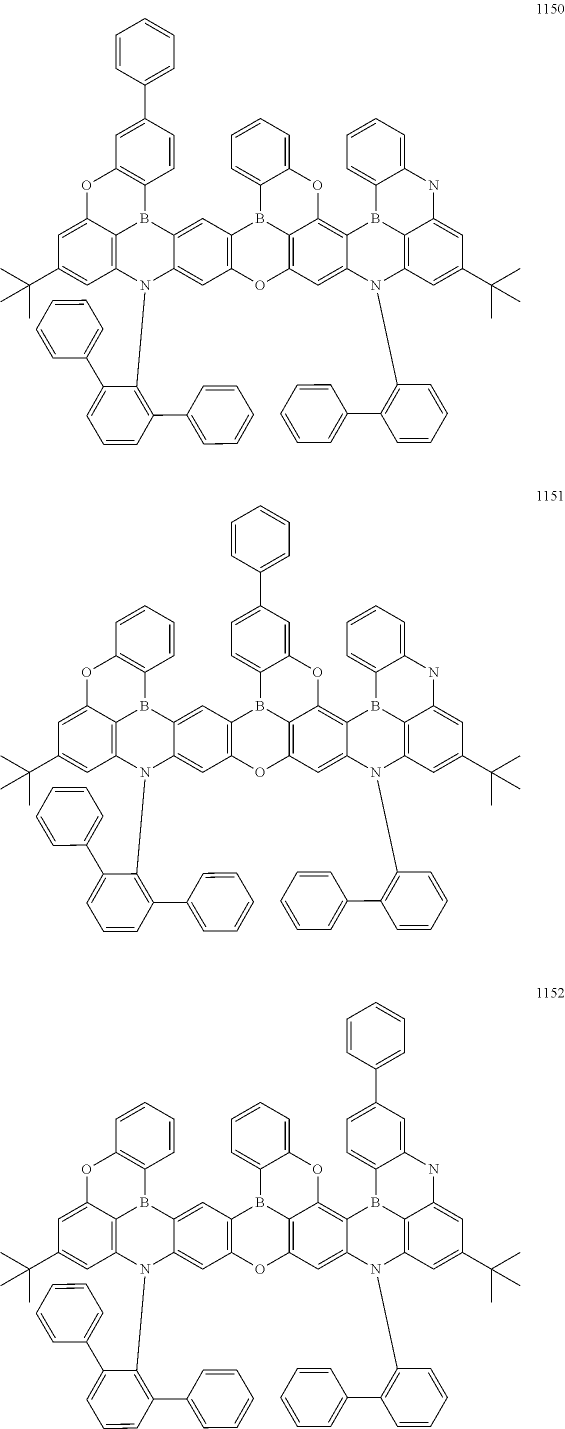 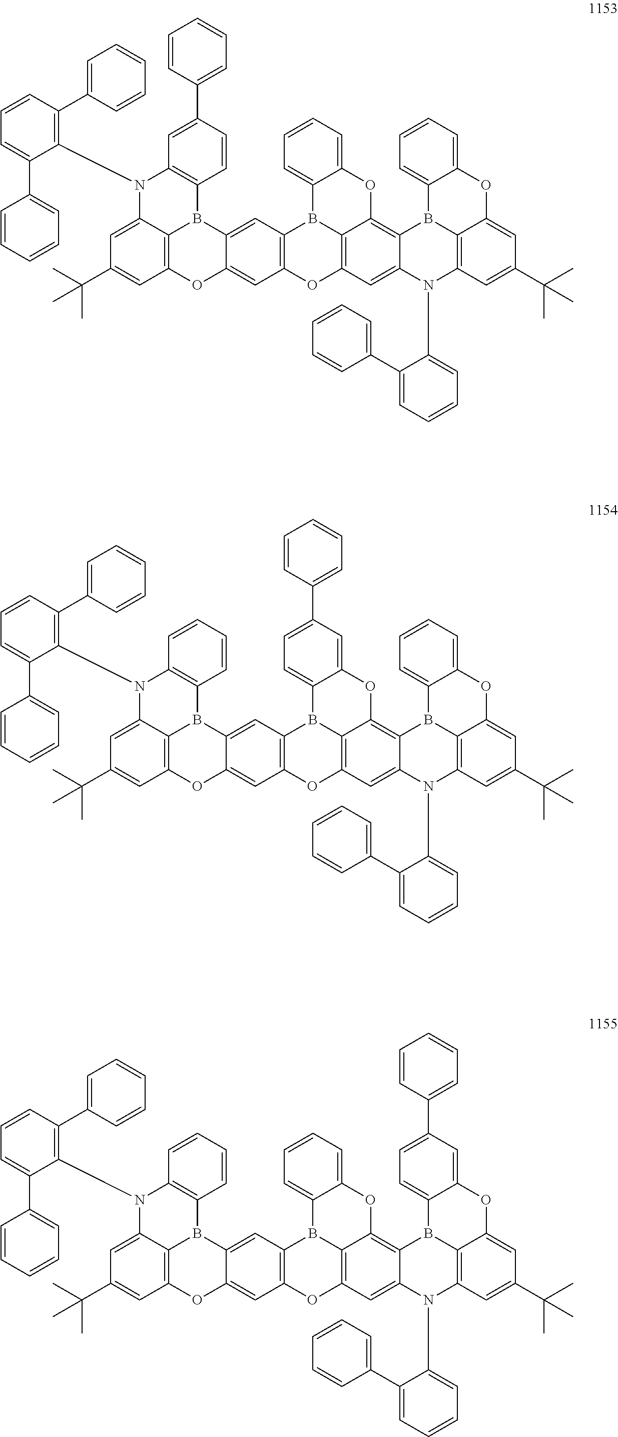 [SMILES: CC(C)(C)c1cc2c3c(c1)N(c1ccccc1-c1ccccc1)c1cc4c5c(c1B3c1ccccc1O2)Oc1ccccc1B5c1cc2c(cc1O4)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1ccccc1-c1ccccc1)c1cc4c5c(c1B3c1ccccc1O2)Oc1cc(-c2ccccc2)ccc1B5c1cc2c(cc1O4)Oc1cc(C(C)(C)C)cc3c1B2c1ccccc1N3c1c(-c2ccccc2)cccc1-c1ccccc1 ; CC(C)(C)c1cc2c3c(c1)N(c1ccccc1-c1ccccc1)c1cc4c5c(c1B3c1ccc(-c3ccccc3)cc1O2)Oc1ccccc1B5c1cc2c(cc1O4)Oc1cc(C(C)(C)C)cc3c1B2c1ccccc1N3c1c(-c2ccccc2)cccc1-c1ccccc1] 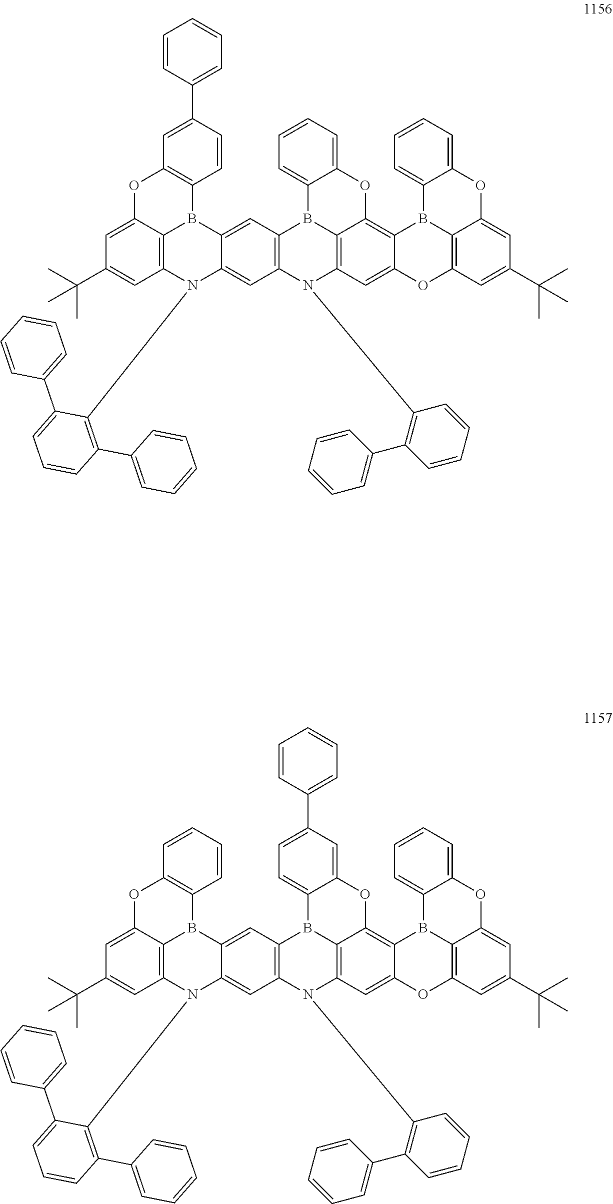 [SMILES: CC(C)(C)c1cc2c3c(c1)Oc1cc4c5c(c1B3c1ccccc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-c2ccccc2)cc1O3 ; CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)N(c1c(-c3ccccc3)cccc1-c1ccccc1)c1cc(C(C)(C)C)cc3c1B2c1ccccc1O3] 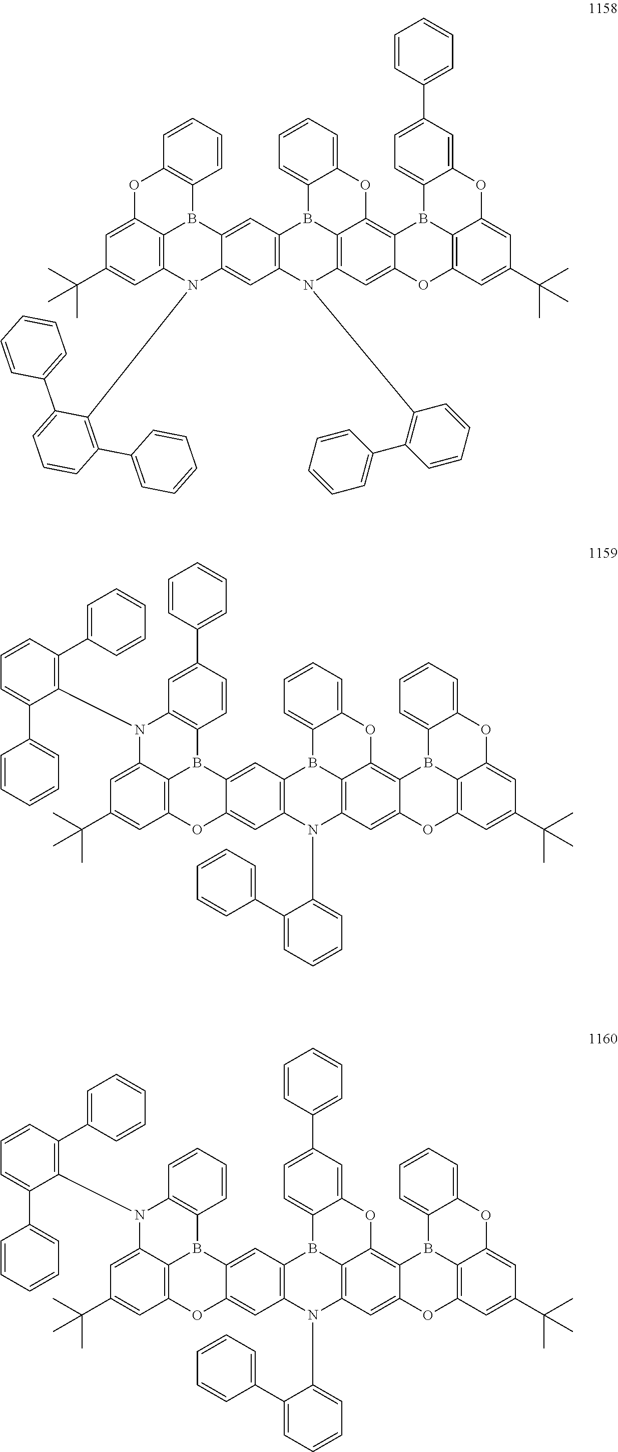 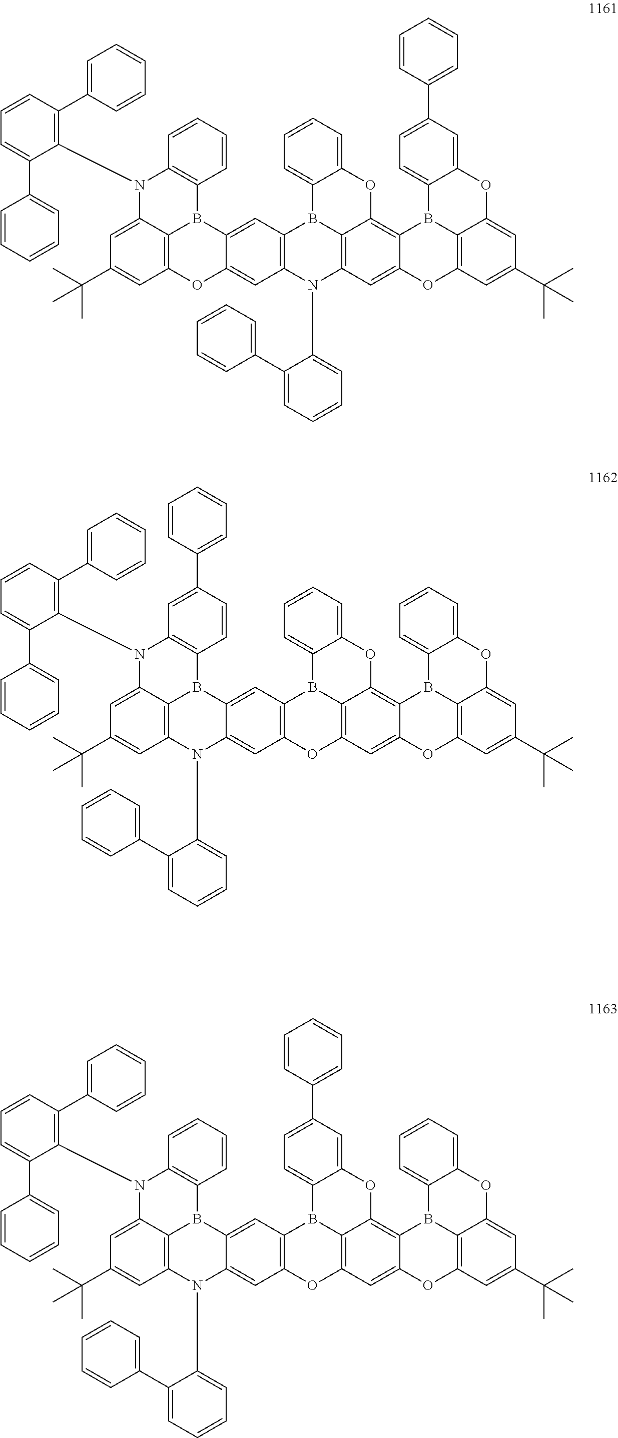 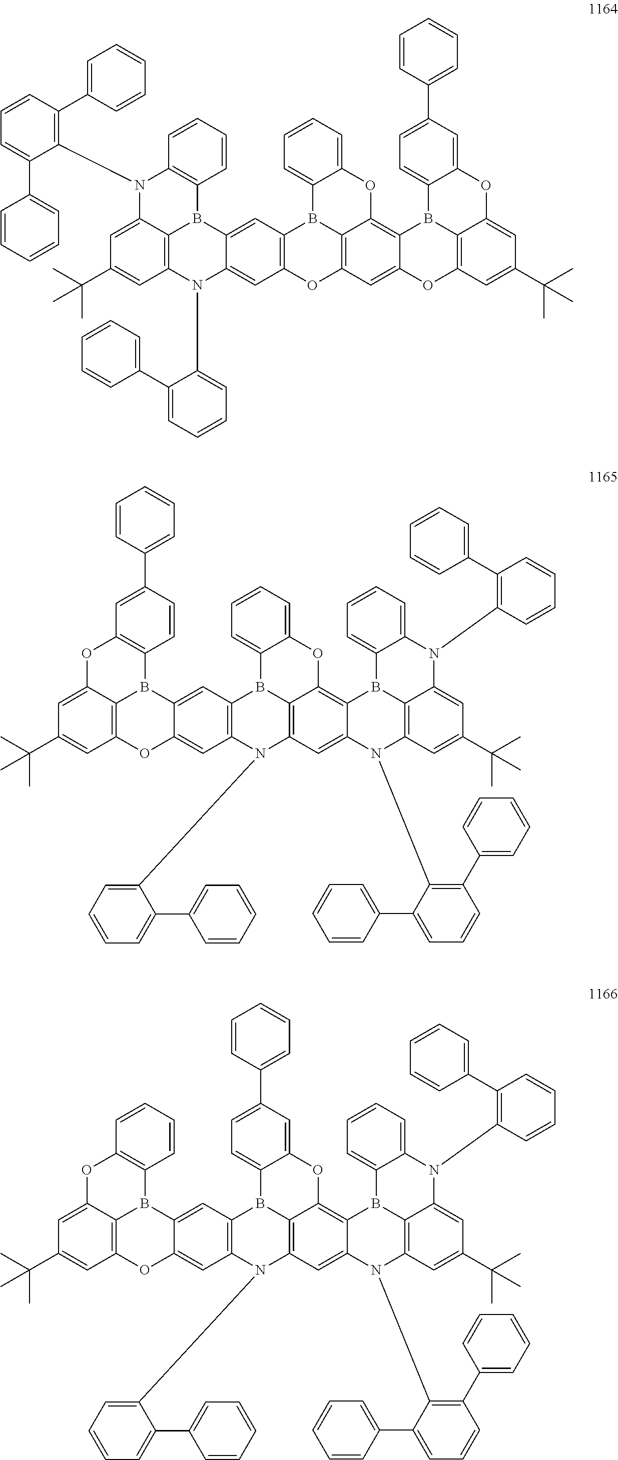 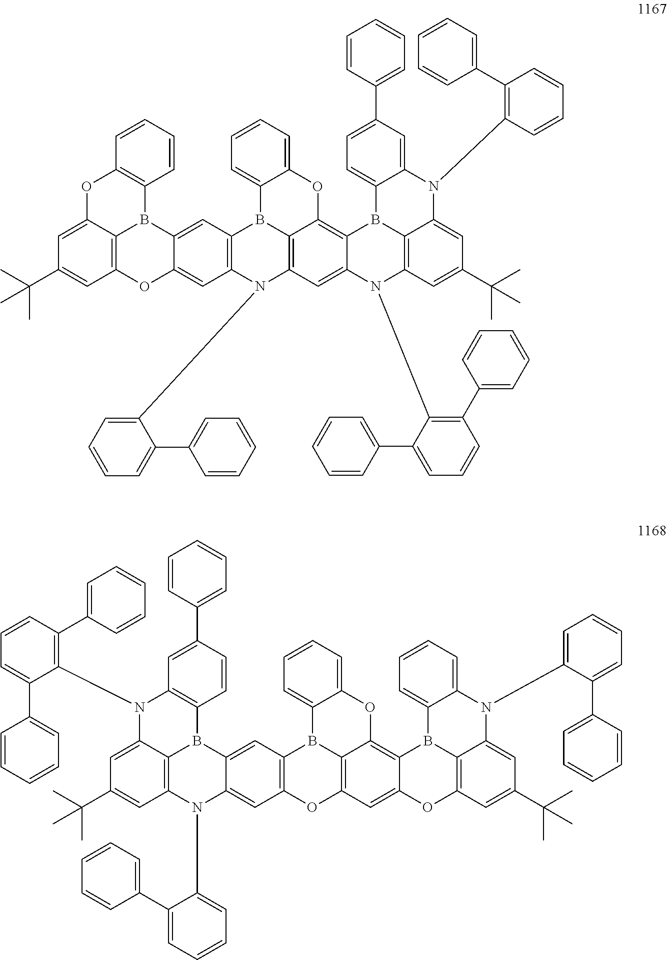 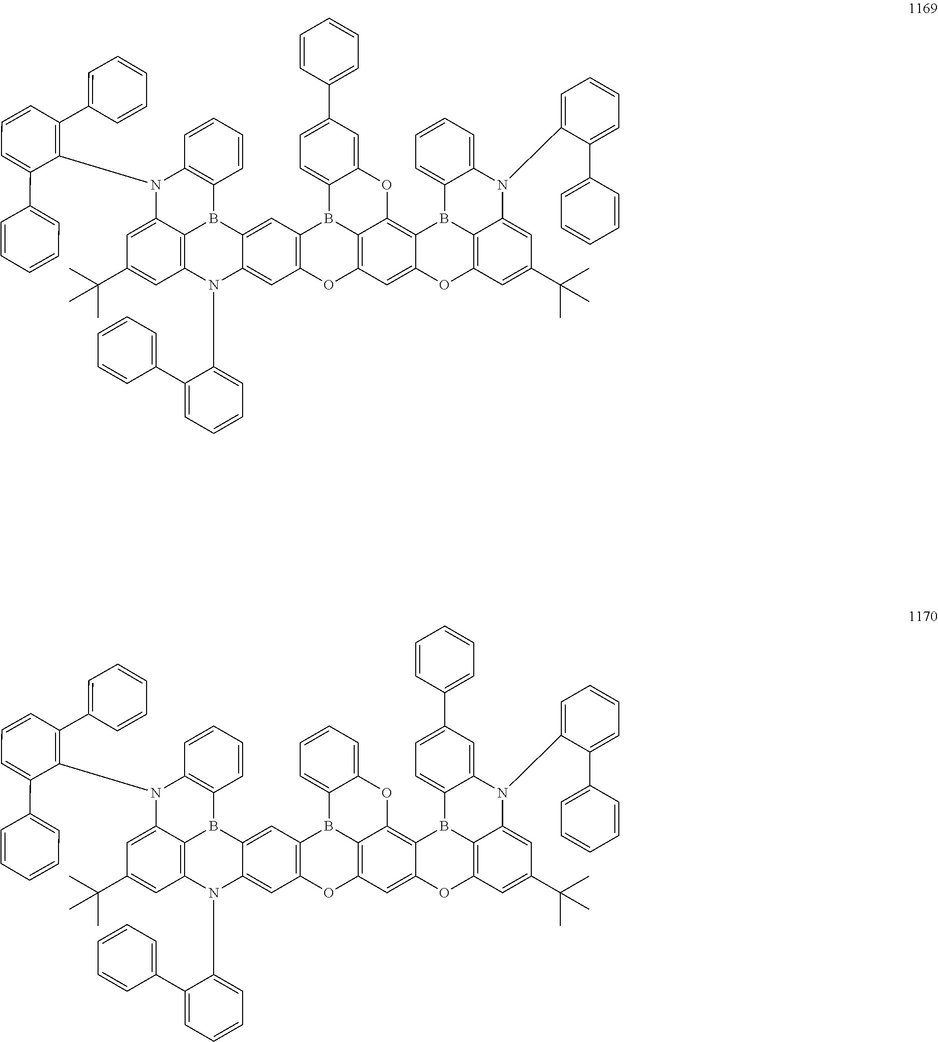 [SMILES: CC(C)(C)c1cc2c3c(c1)N(c1ccccc1-c1ccccc1)c1ccccc1B3c1c(cc3c4c1Oc1cc(-c5ccccc5)ccc1B4c1cc4c(cc1O3)N(c1ccccc1-c1ccccc1)c1cc(C(C)(C)C)cc3c1B4c1ccccc1N3c1c(-c3ccccc3)cccc1-c1ccccc1)O2 ; CC(C)(C)c1cc2c3c(c1)N(c1ccccc1-c1ccccc1)c1cc(-c4ccccc4)ccc1B3c1c(cc3c4c1Oc1ccccc1B4c1cc4c(cc1O3)N(c1ccccc1-c1ccccc1)c1cc(C(C)(C)C)cc3c1B4c1ccccc1N3c1c(-c3ccccc3)cccc1-c1ccccc1)O2] 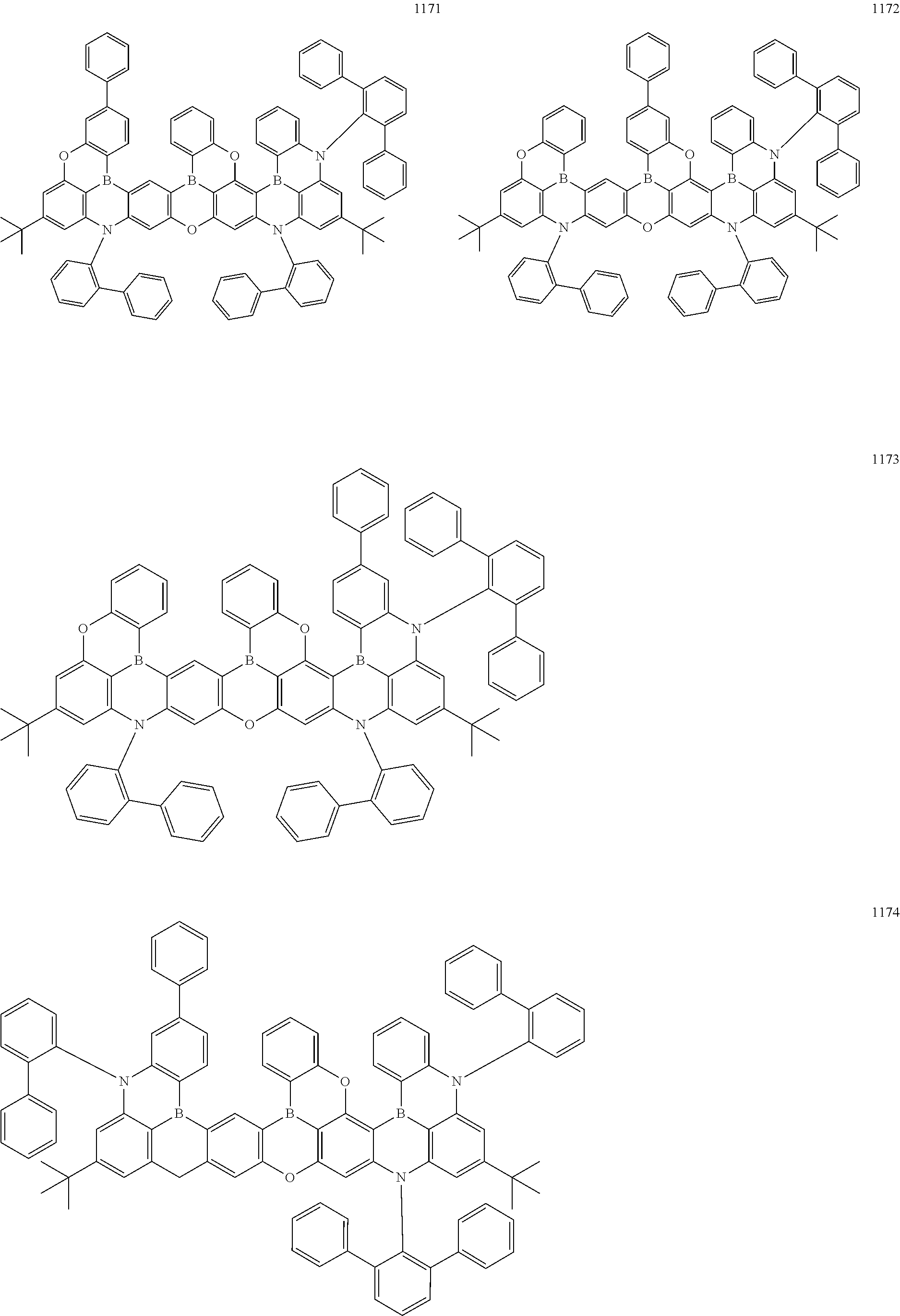 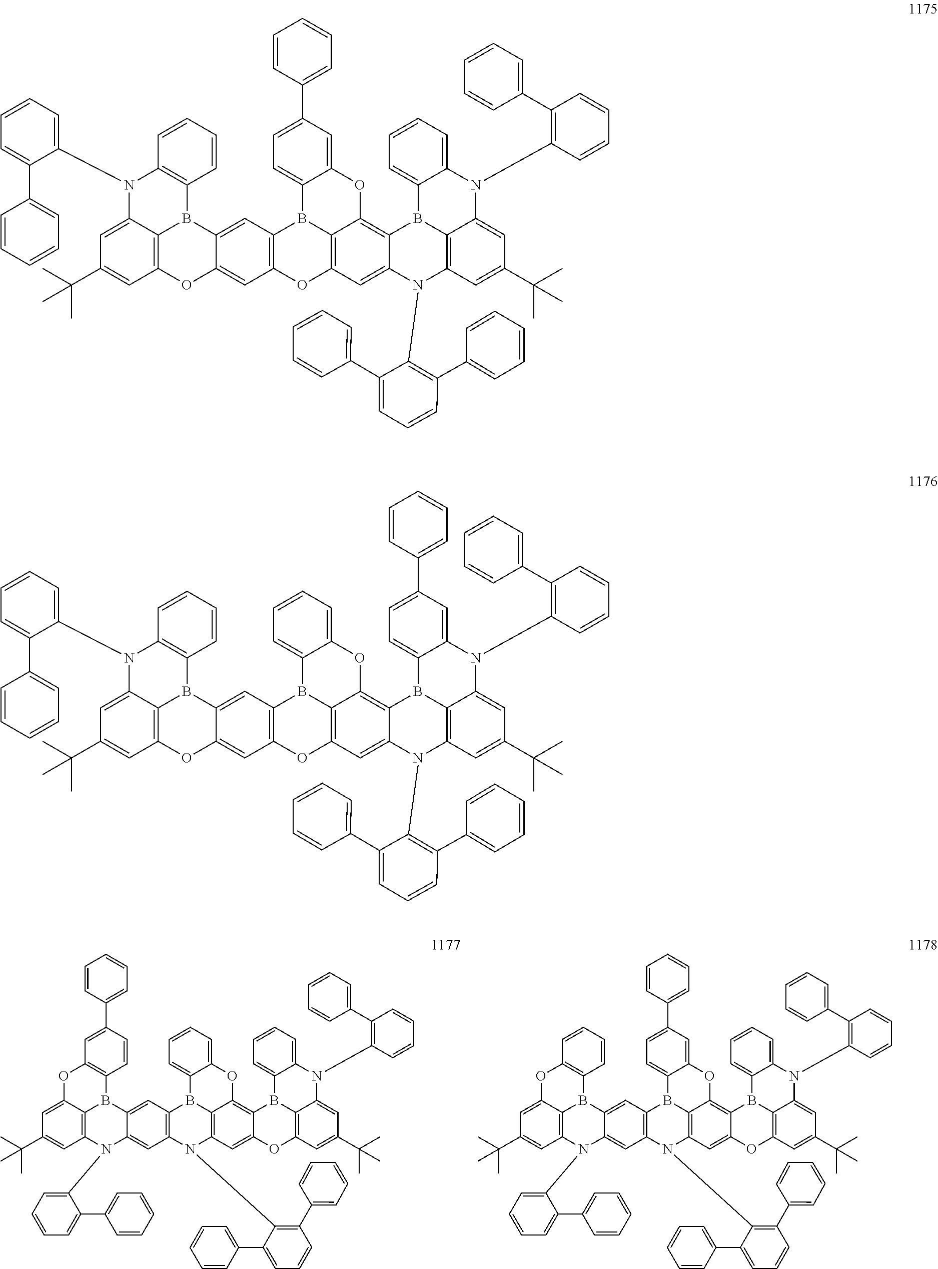 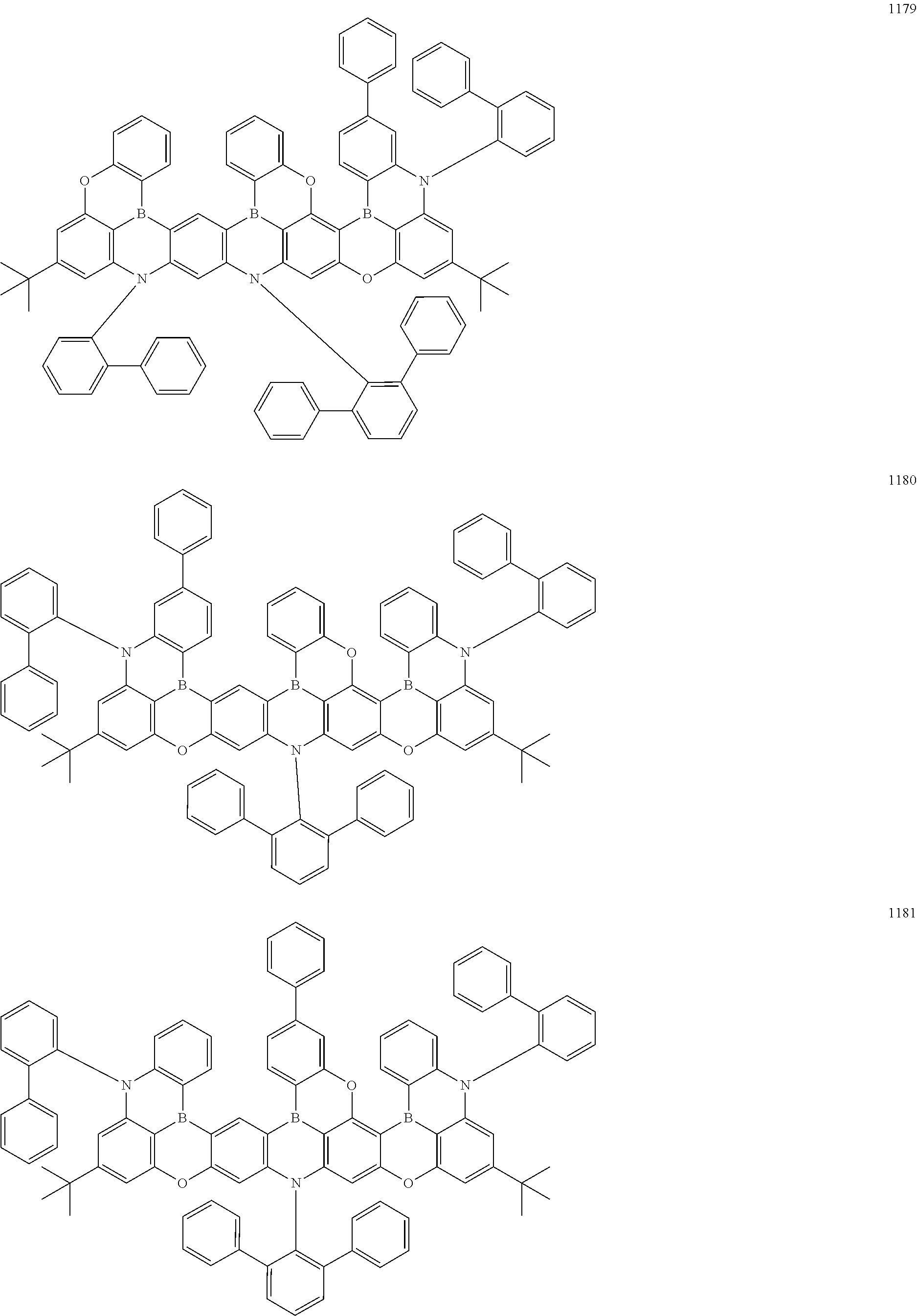 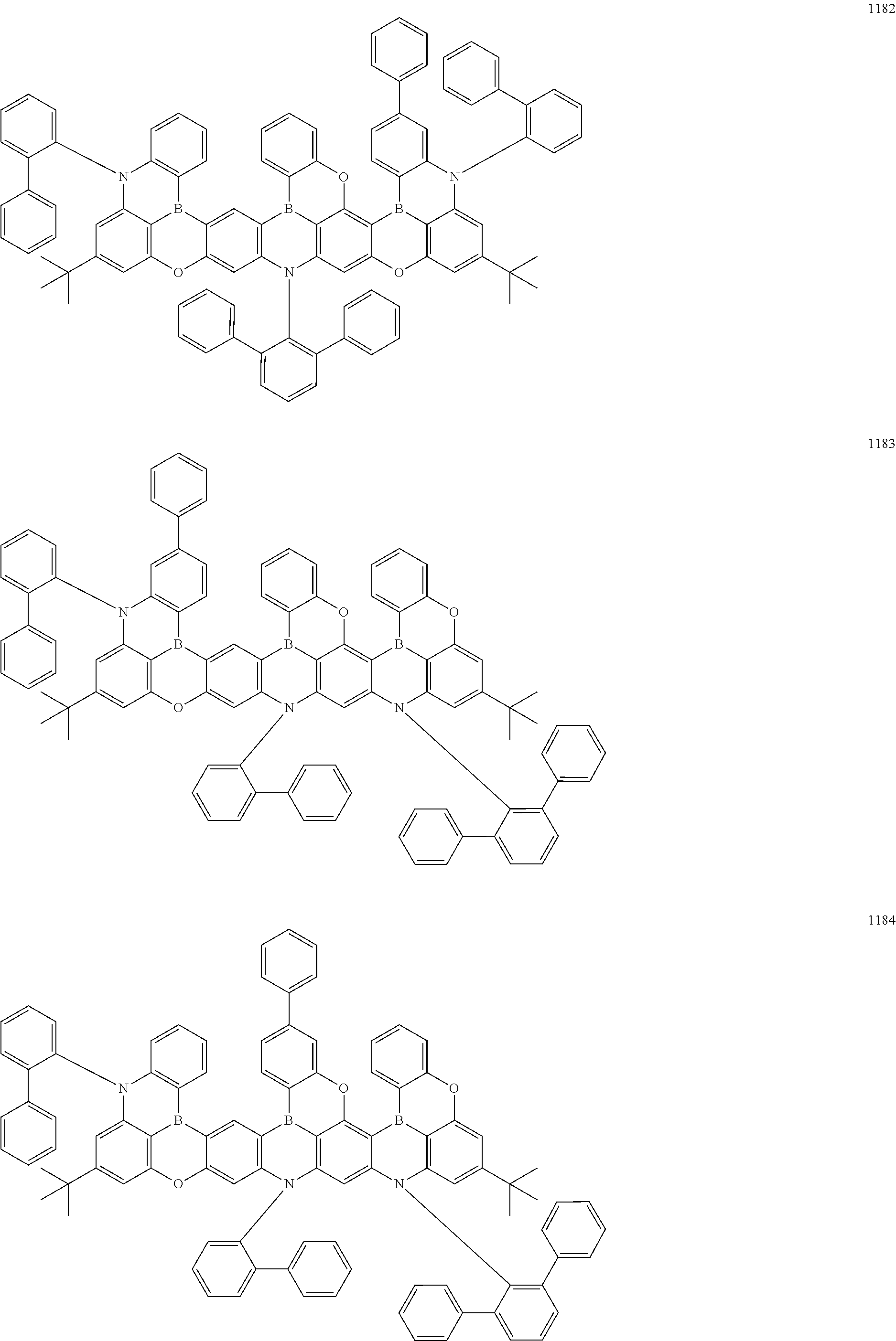 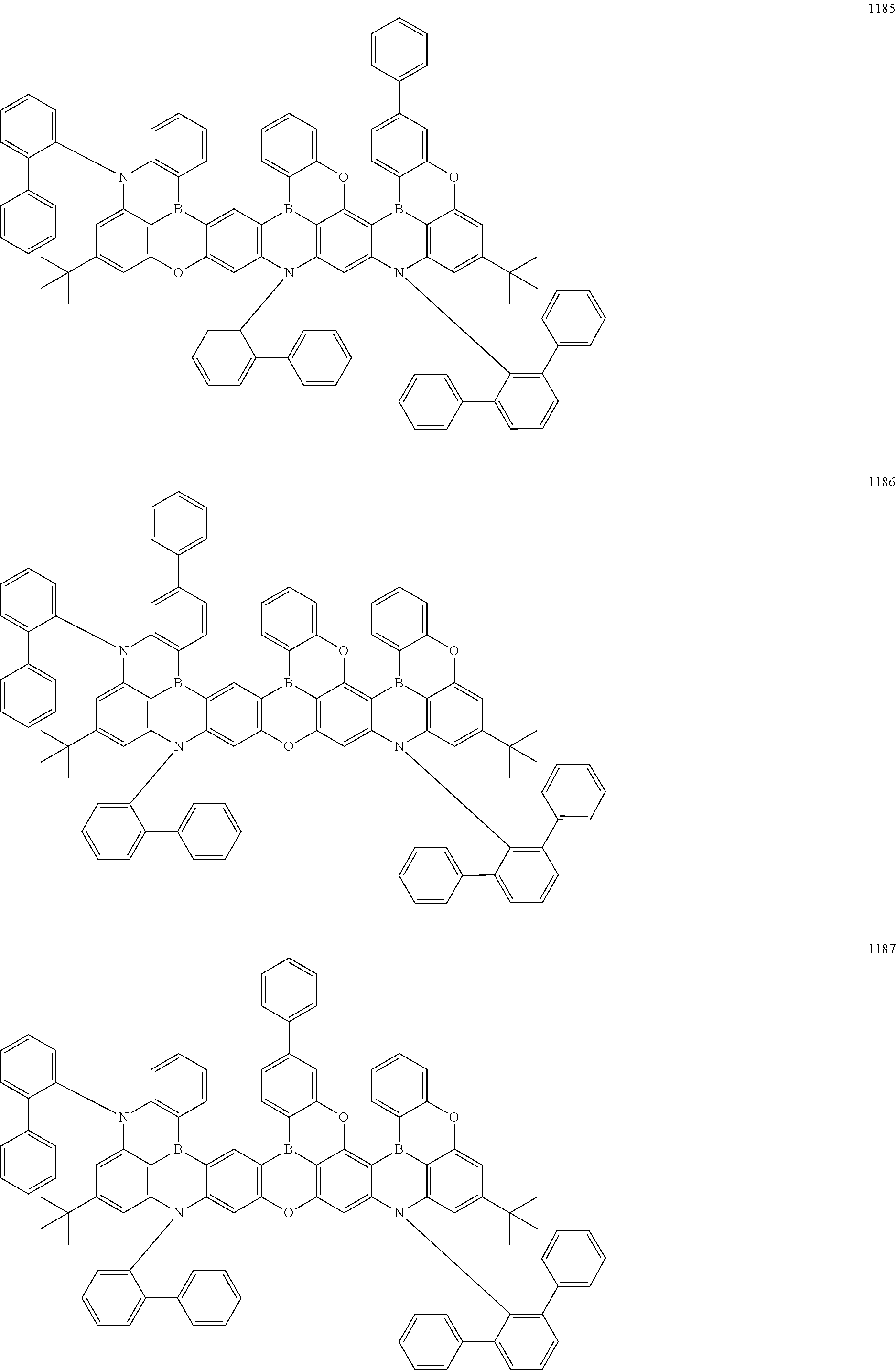 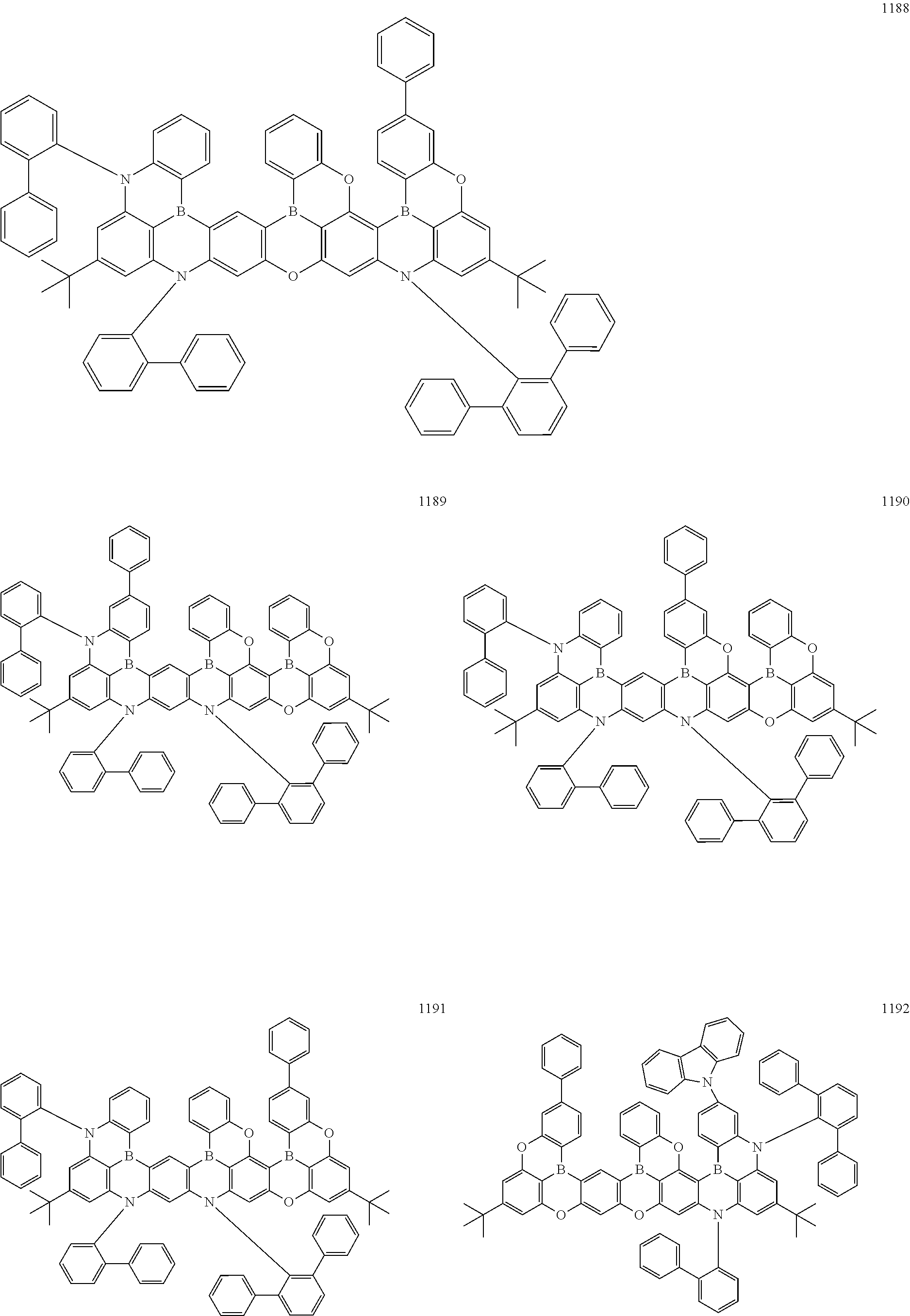 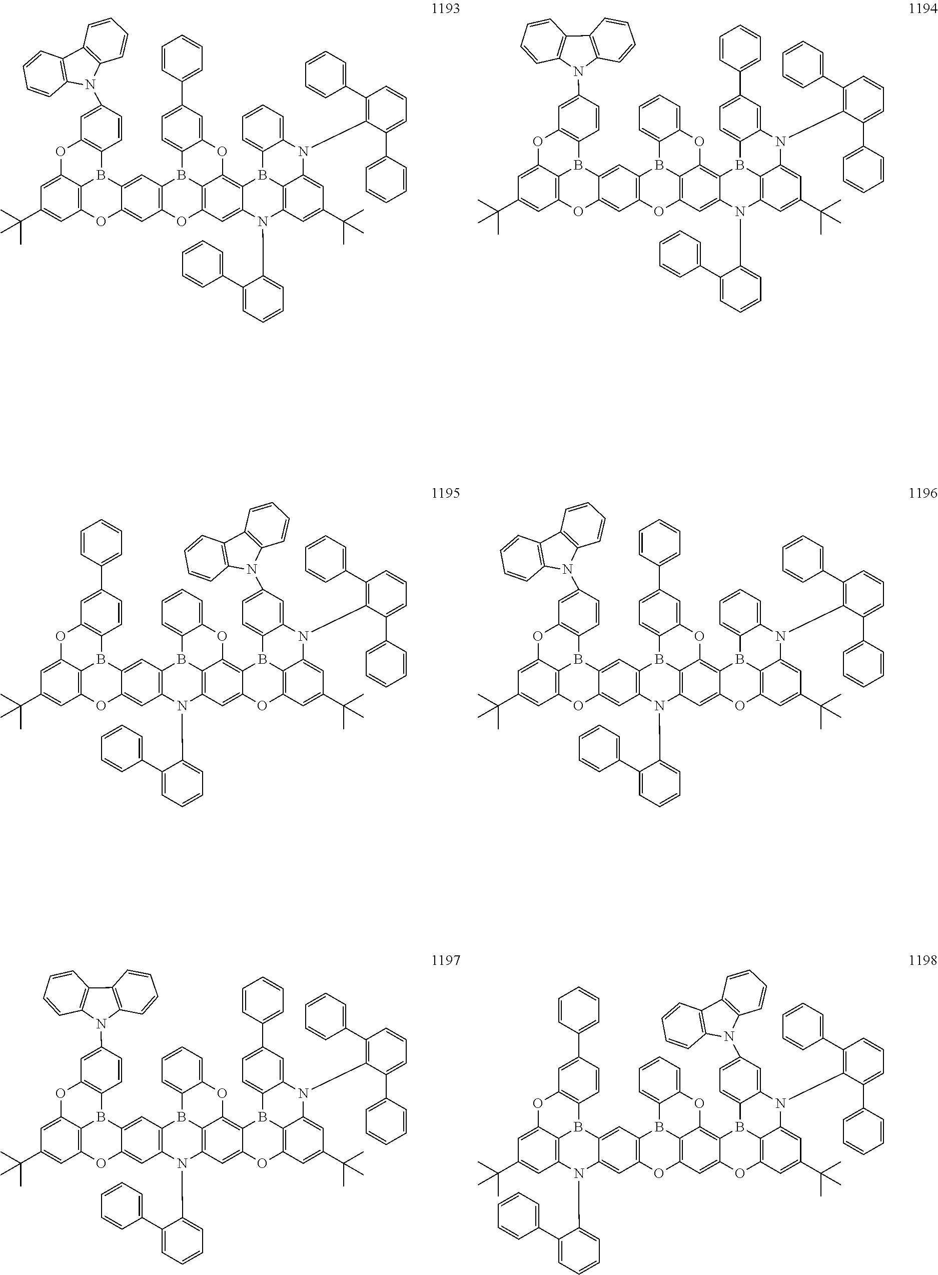 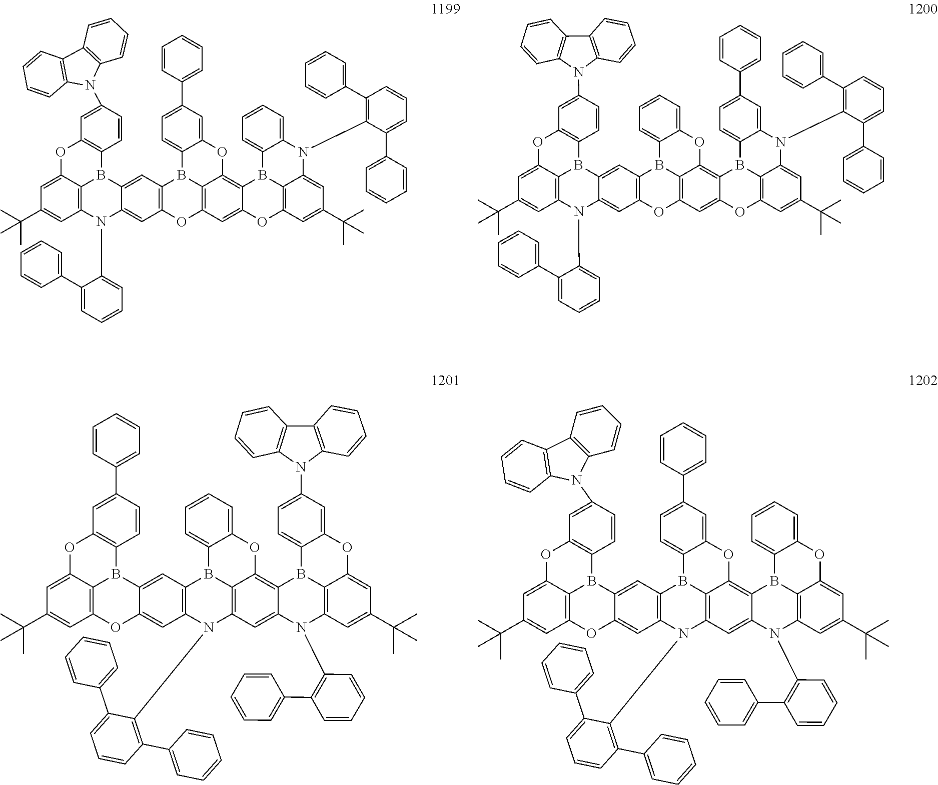 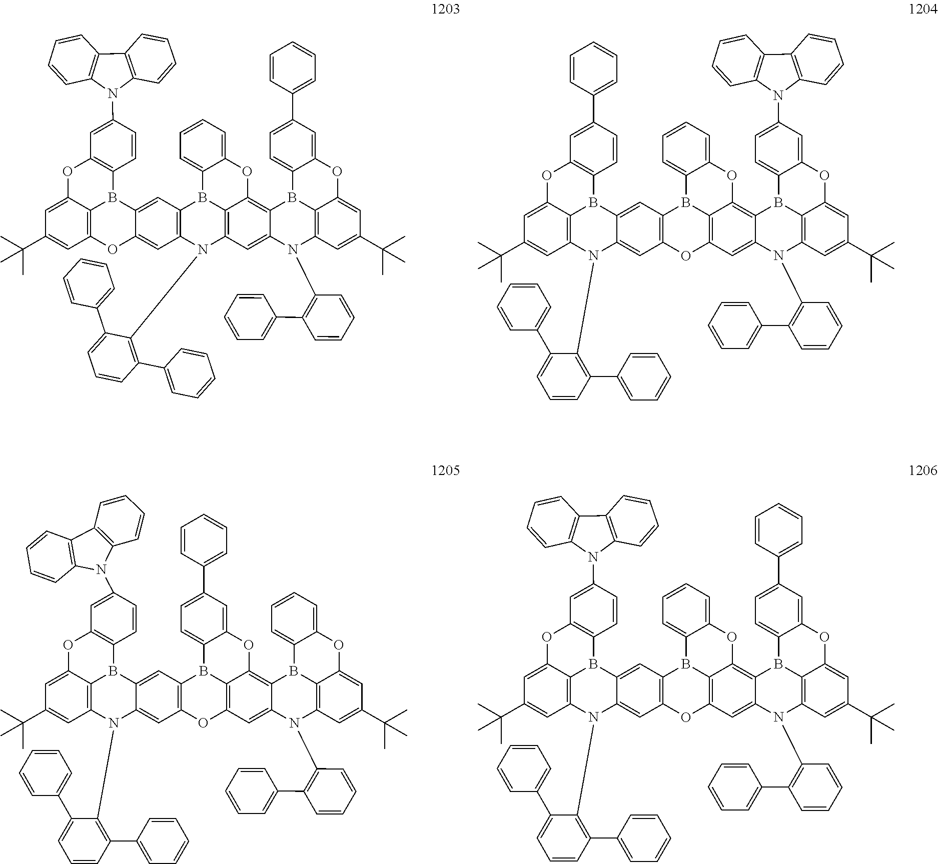 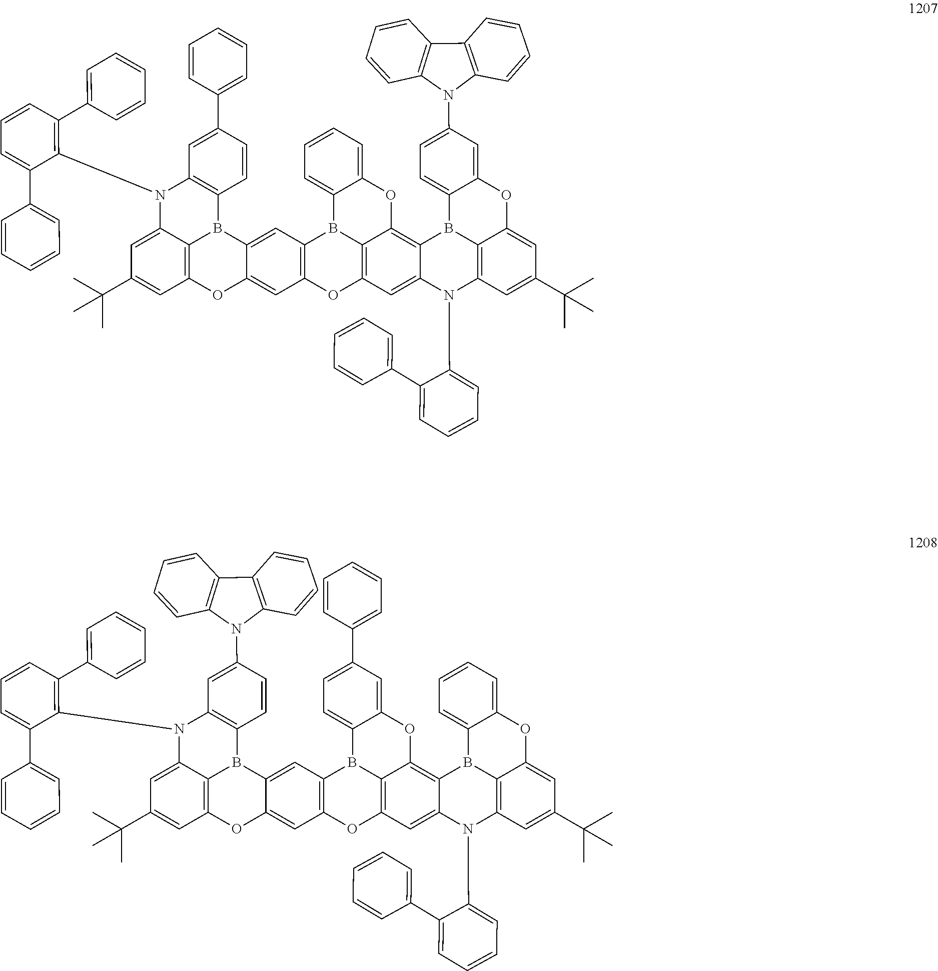 [SMILES: CC(C)(C)c1cc2c3c(c1)N(c1ccccc1-c1ccccc1)c1cc4c5c(c1B3c1ccc(-n3c6ccccc6c6ccccc63)cc1O2)Oc1ccccc1B5c1cc2c(cc1O4)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1ccccc1-c1ccccc1)c1cc4c5c(c1B3c1ccccc1O2)Oc1cc(-c2ccccc2)ccc1B5c1cc2c(cc1O4)Oc1cc(C(C)(C)C)cc3c1B2c1ccc(-n2c4ccccc4c4ccccc42)cc1N3c1c(-c2ccccc2)cccc1-c1ccccc1] 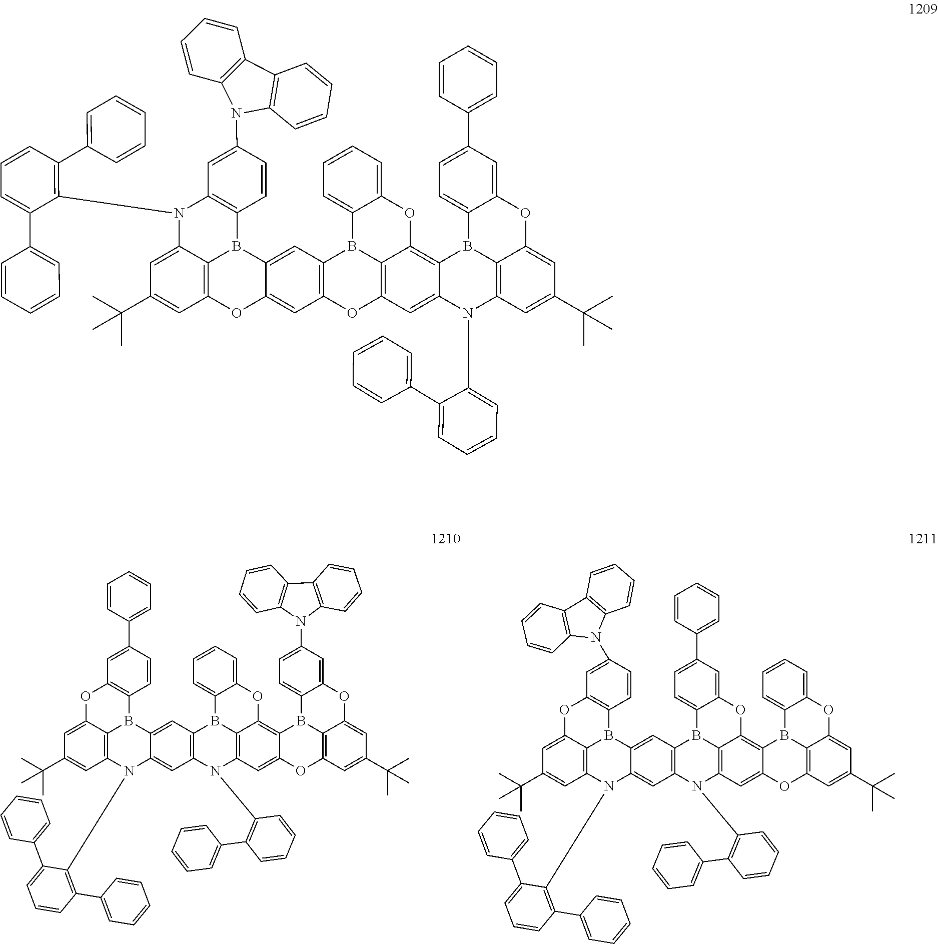 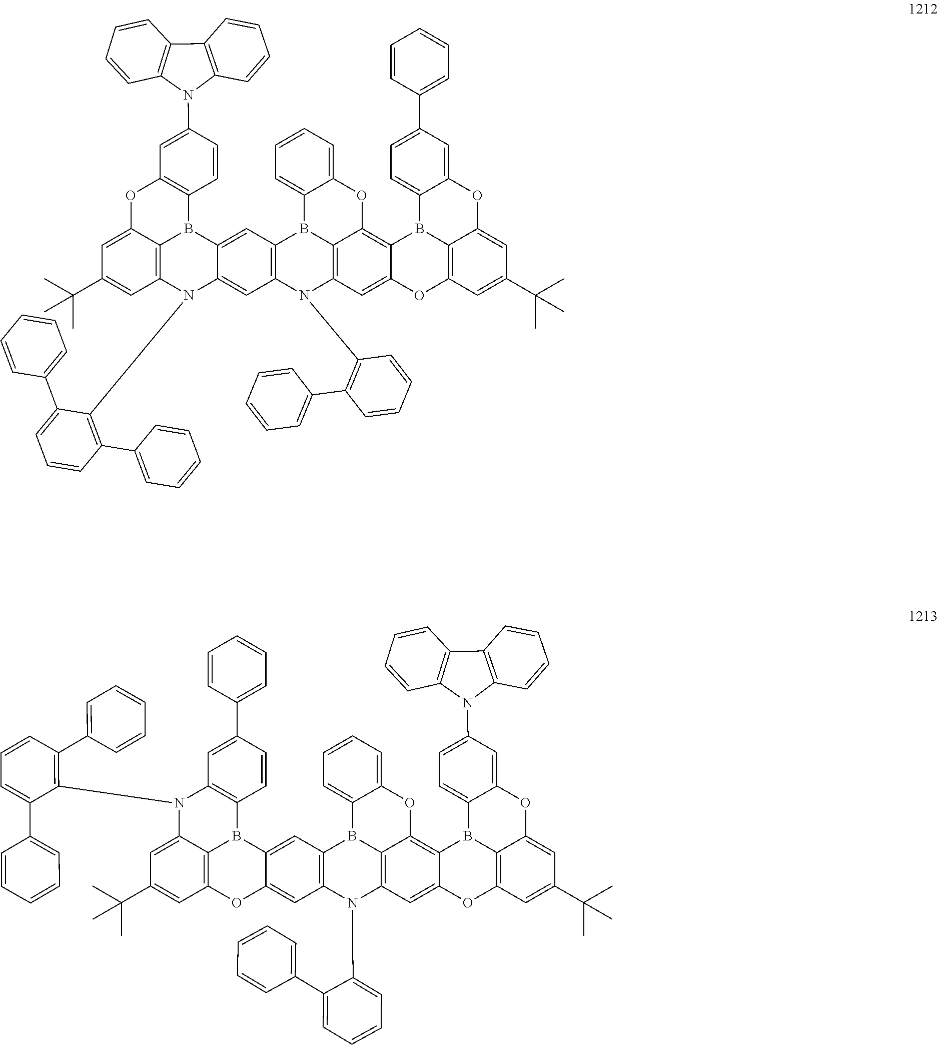 [SMILES: CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)N(c1c(-c3ccccc3)cccc1-c1ccccc1)c1cc(C(C)(C)C)cc3c1B2c1ccc(-n2c4ccccc4c4ccccc42)cc1O3 ; CC(C)(C)c1cc2c3c(c1)Oc1cc4c5c(c1B3c1ccc(-n3c6ccccc6c6ccccc63)cc1O2)Oc1ccccc1B5c1cc2c(cc1N4c1ccccc1-c1ccccc1)Oc1cc(C(C)(C)C)cc3c1B2c1ccc(-c2ccccc2)cc1N3c1c(-c2ccccc2)cccc1-c1ccccc1] 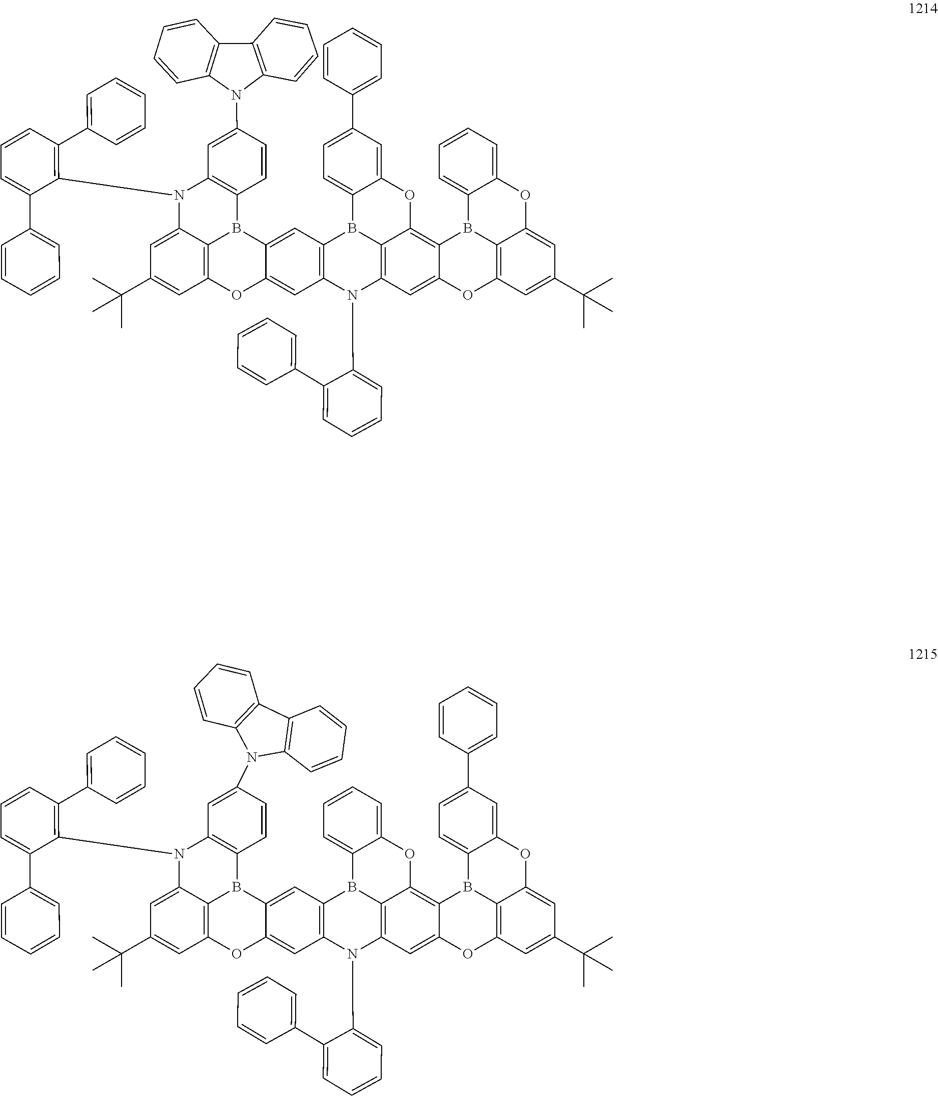 [SMILES: CC(C)(C)c1cc2c3c(c1)Oc1cc4c5c(c1B3c1ccccc1O2)Oc1cc(-c2ccccc2)ccc1B5c1cc2c(cc1N4c1ccccc1-c1ccccc1)Oc1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)Oc1cc4c5c(c1B3c1ccc(-c3ccccc3)cc1O2)Oc1ccccc1B5c1cc2c(cc1N4c1ccccc1-c1ccccc1)Oc1cc(C(C)(C)C)cc3c1B2c1ccc(-n2c4ccccc4c4ccccc42)cc1N3c1c(-c2ccccc2)cccc1-c1ccccc1] 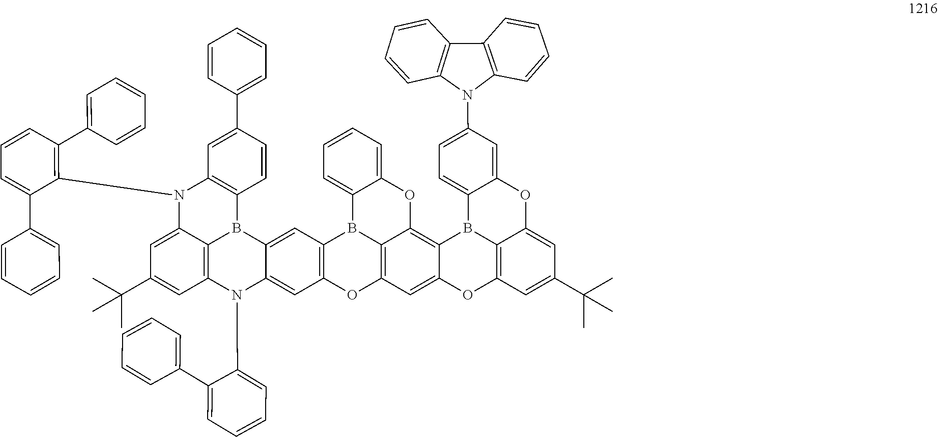 [SMILES: CC(C)(C)c1cc2c3c(c1)Oc1cc4c5c(c1B3c1ccc(-n3c6ccccc6c6ccccc63)cc1O2)Oc1ccccc1B5c1cc2c(cc1O4)N(c1ccccc1-c1ccccc1)c1cc(C(C)(C)C)cc3c1B2c1ccc(-c2ccccc2)cc1N3c1c(-c2ccccc2)cccc1-c1ccccc1] 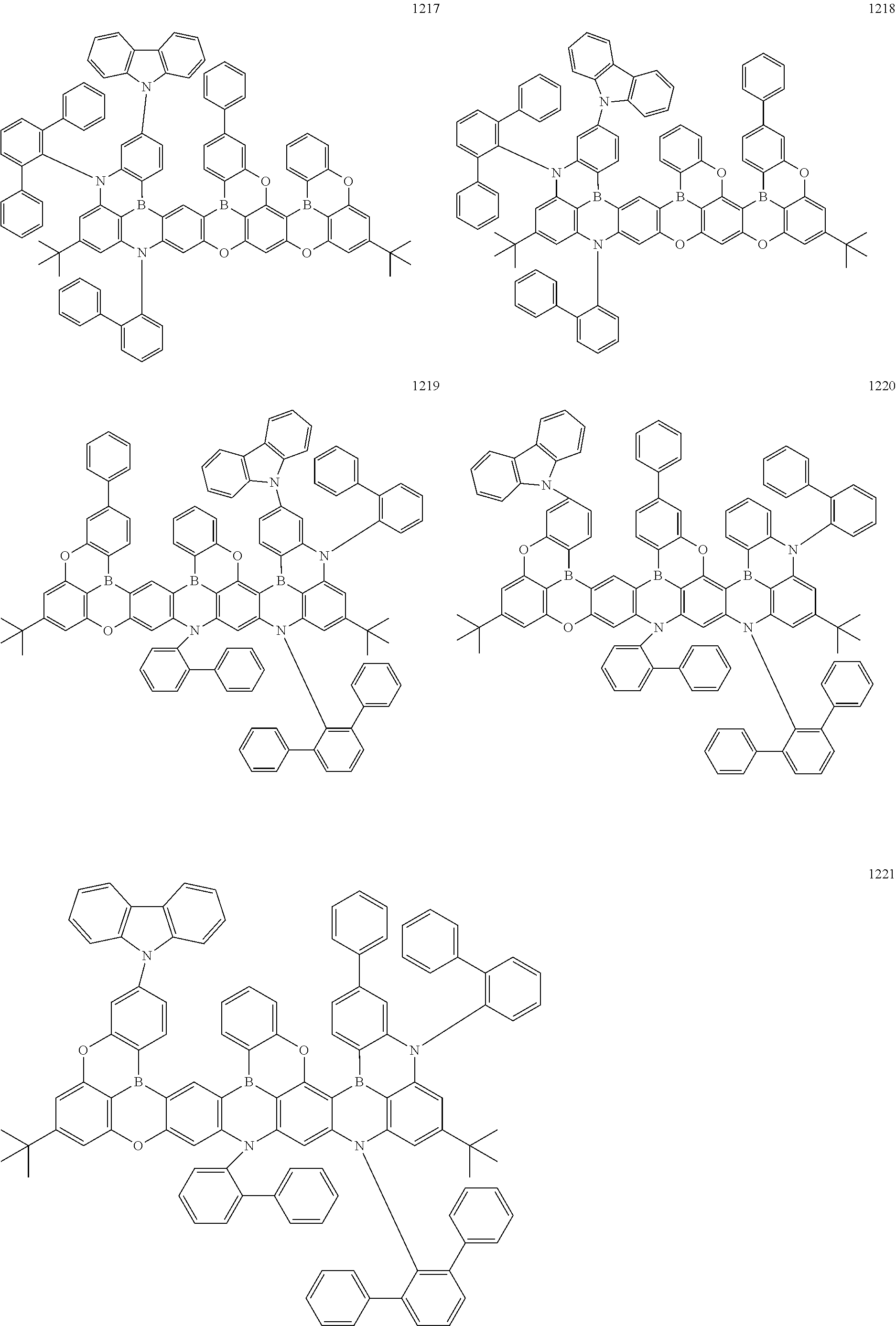 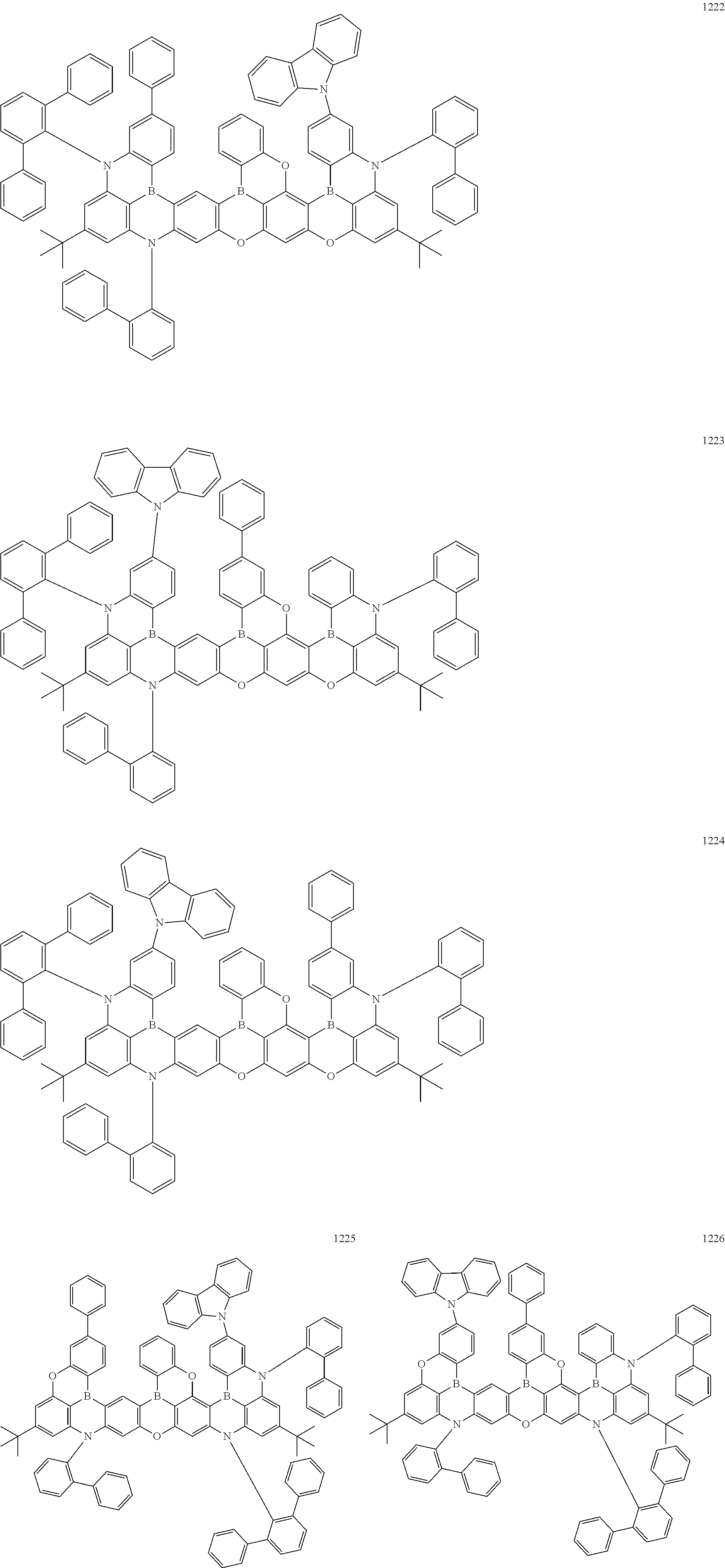 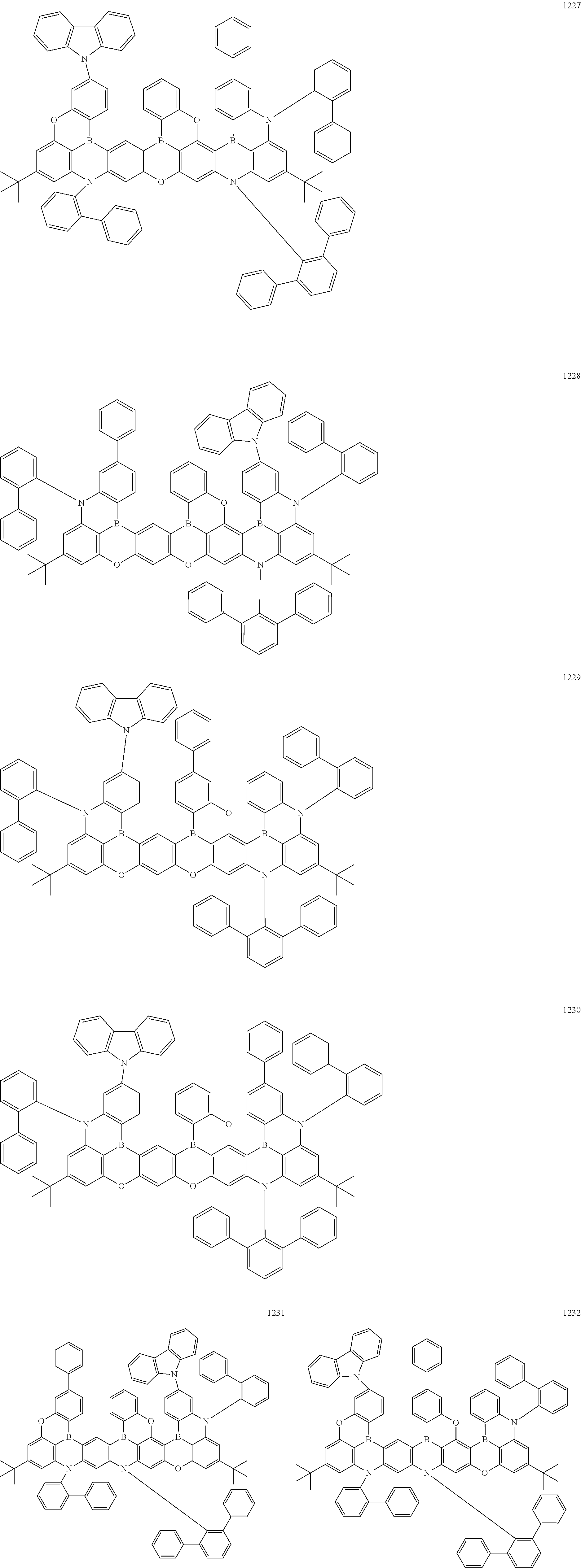 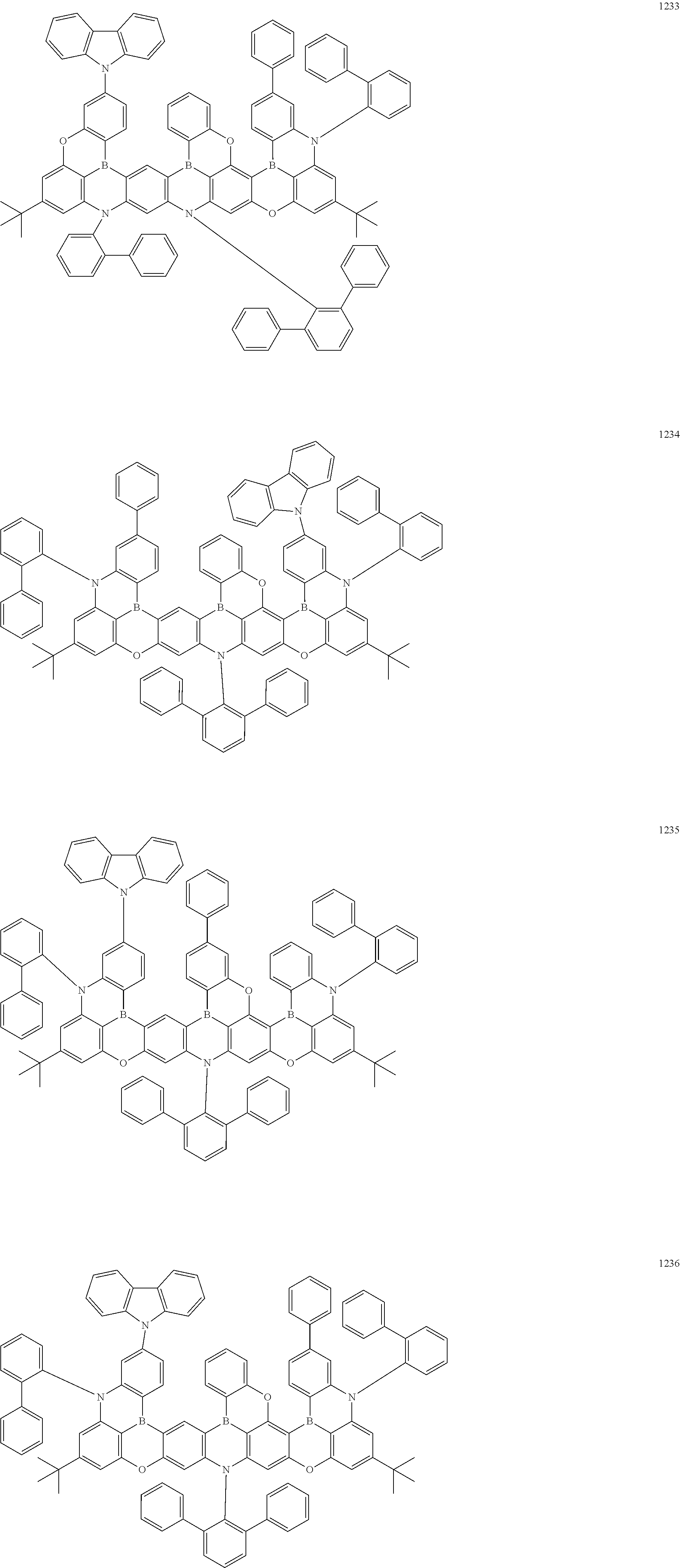 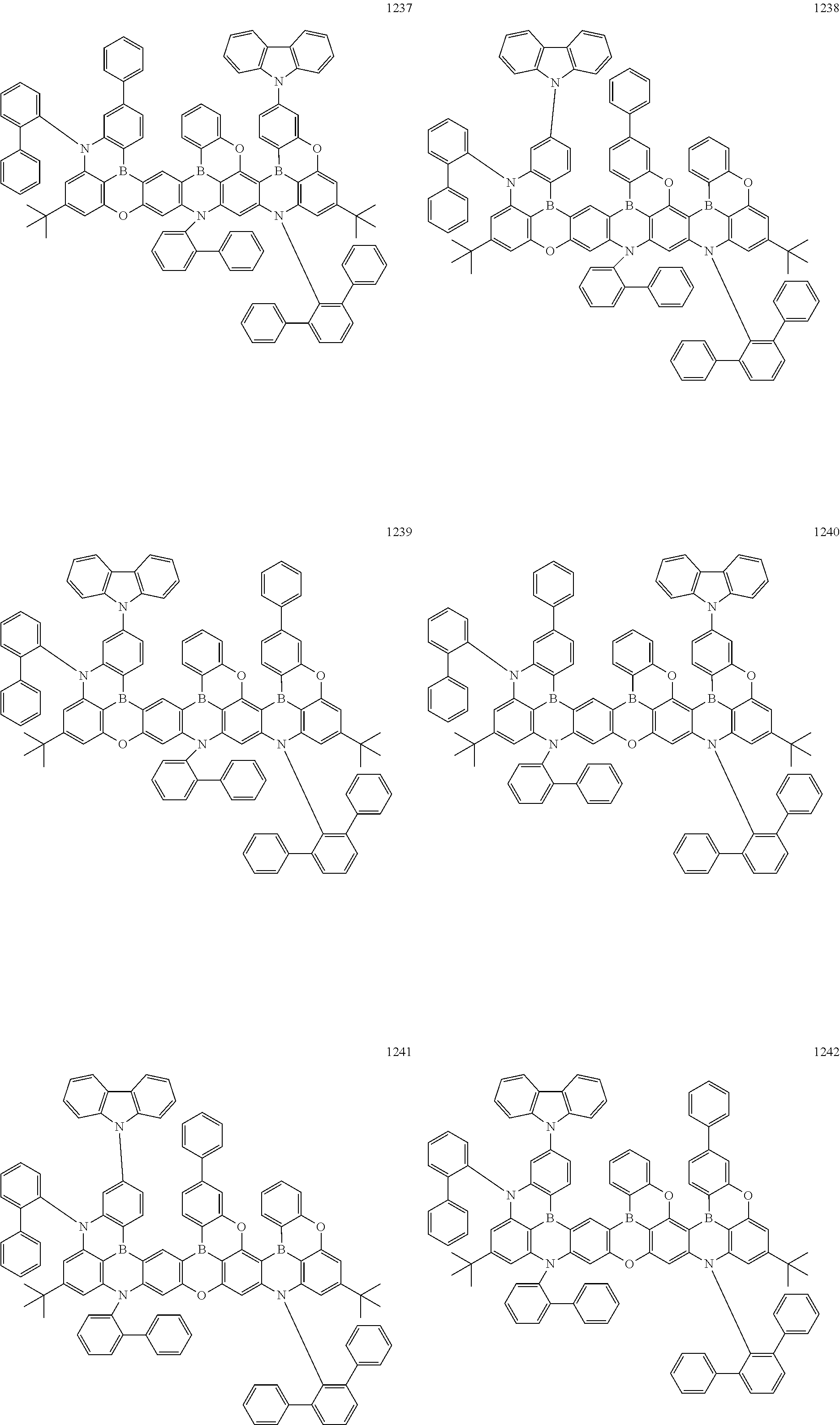 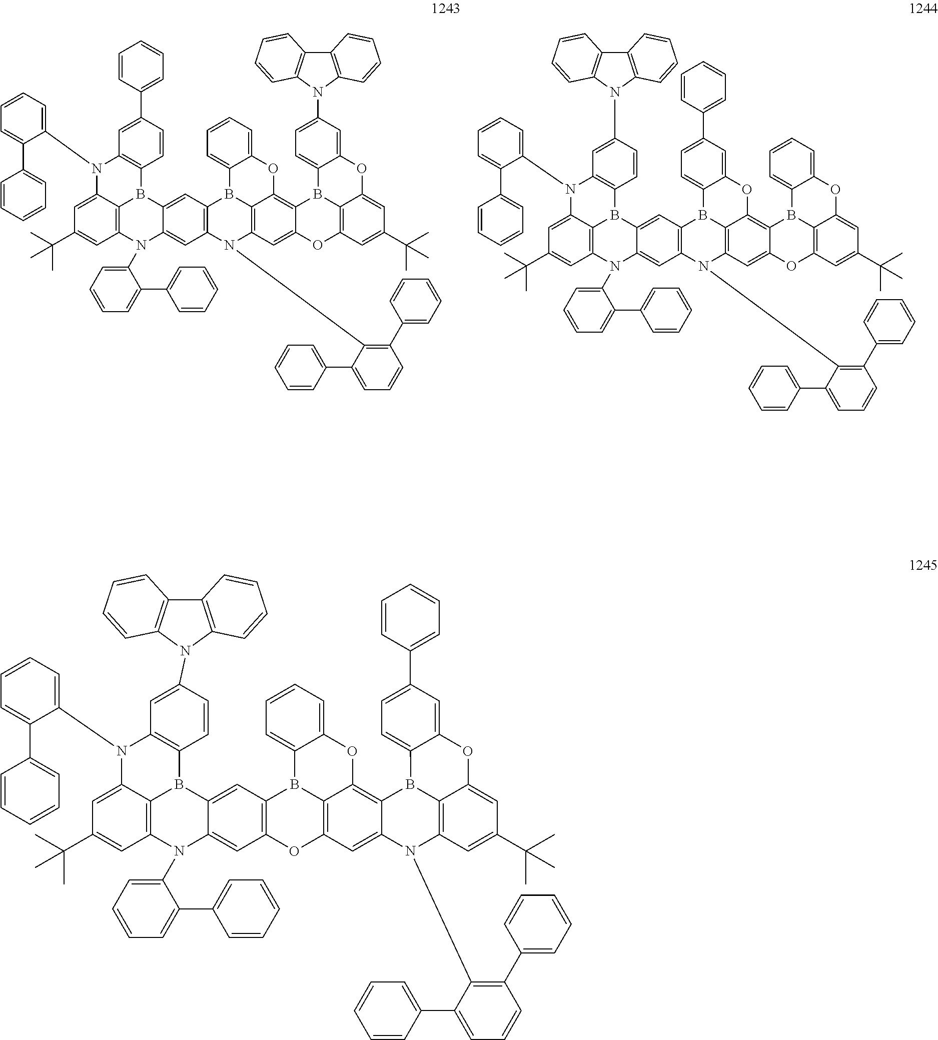 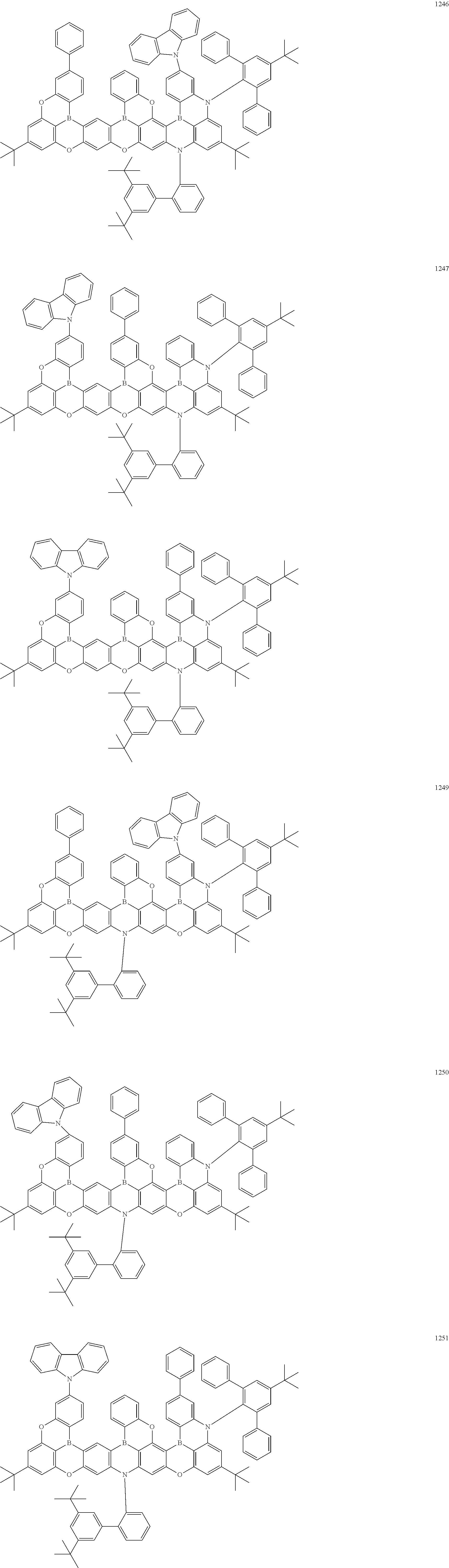 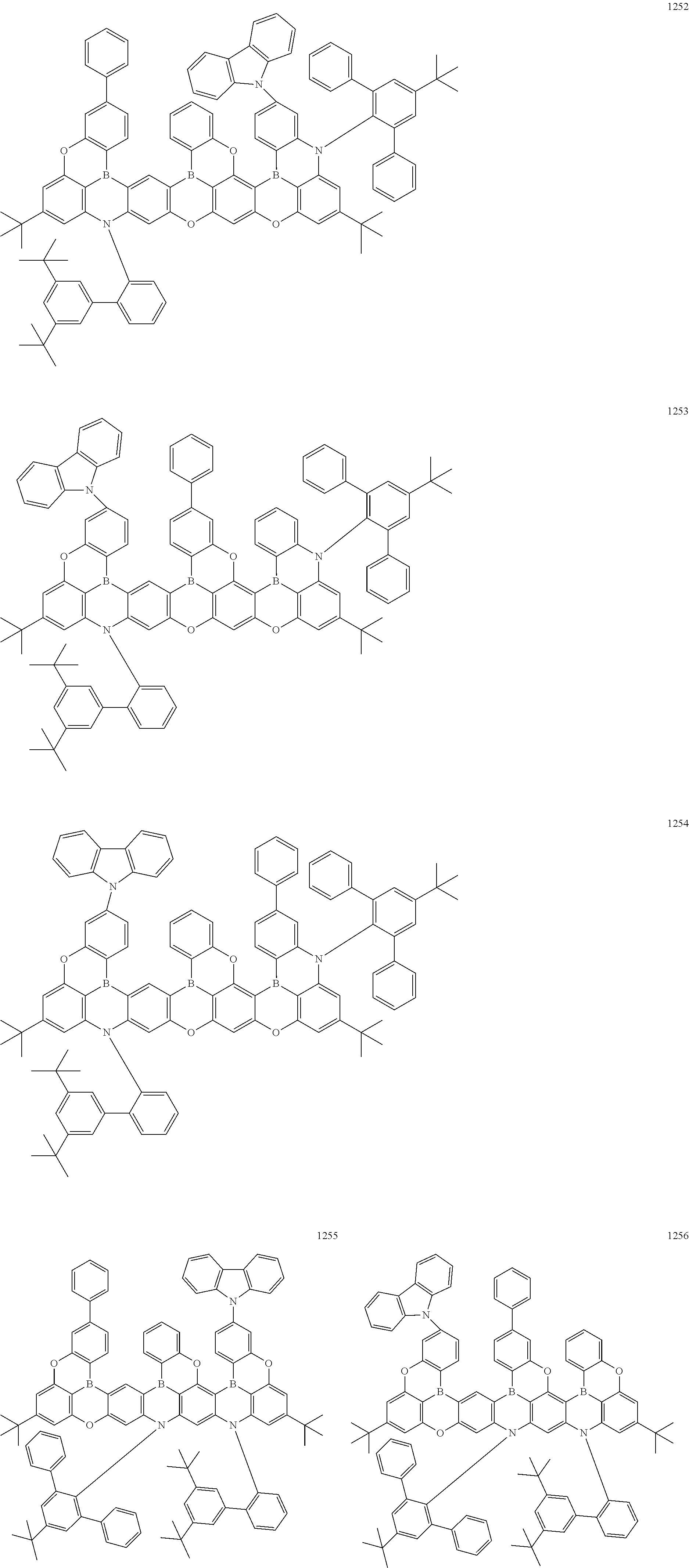 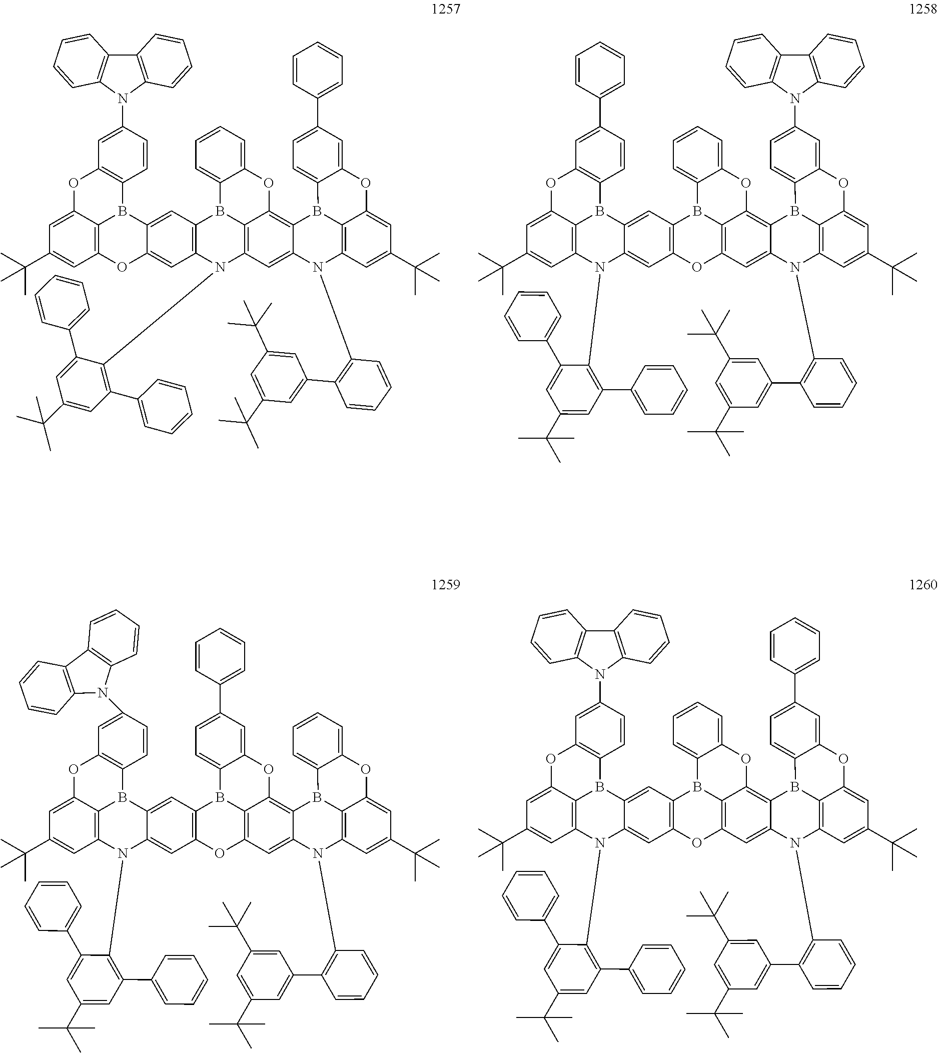 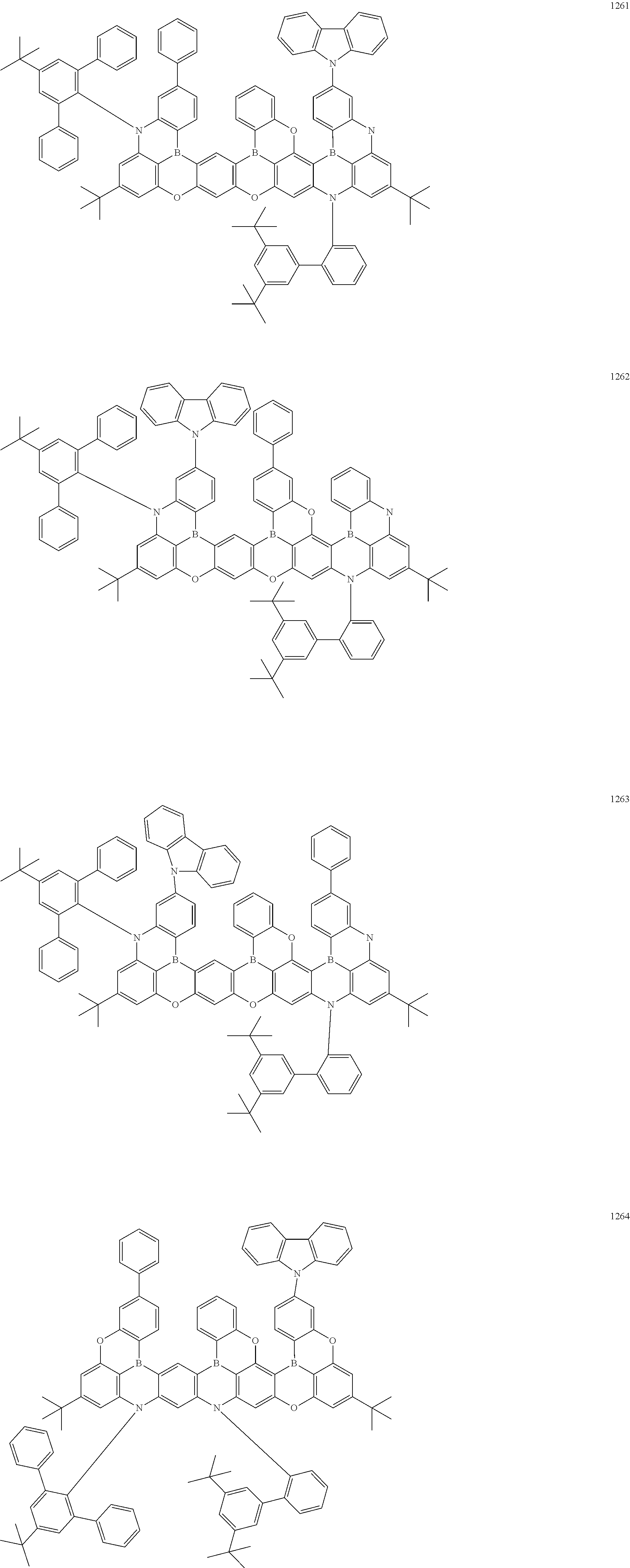 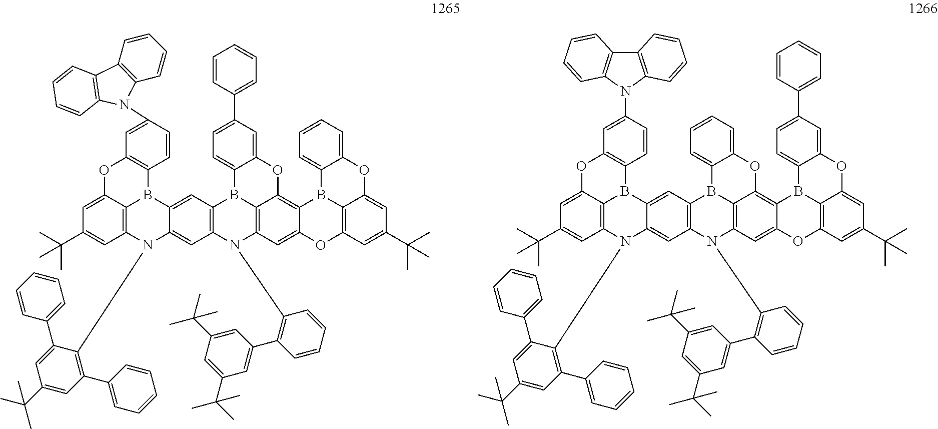 [SMILES: CC(C)(C)c1cc(-c2ccccc2N2c3cc4c(cc3B3c5ccc(-c6ccccc6)cc5Oc5c6c(cc2c53)Oc2cc(C(C)(C)C)cc3c2B6c2ccccc2O3)B2c3ccc(-n5c6ccccc6c6ccccc65)cc3Oc3cc(C(C)(C)C)cc(c32)N4c2c(-c3ccccc3)cc(C(C)(C)C)cc2-c2ccccc2)cc(C(C)(C)C)c1 ; CC(C)(C)c1cc(-c2ccccc2N2c3cc4c(cc3B3c5ccccc5Oc5c6c(cc2c53)Oc2cc(C(C)(C)C)cc3c2B6c2ccc(-c5ccccc5)cc2O3)B2c3ccc(-n5c6ccccc6c6ccccc65)cc3Oc3cc(C(C)(C)C)cc(c32)N4c2c(-c3ccccc3)cc(C(C)(C)C)cc2-c2ccccc2)cc(C(C)(C)C)c1] 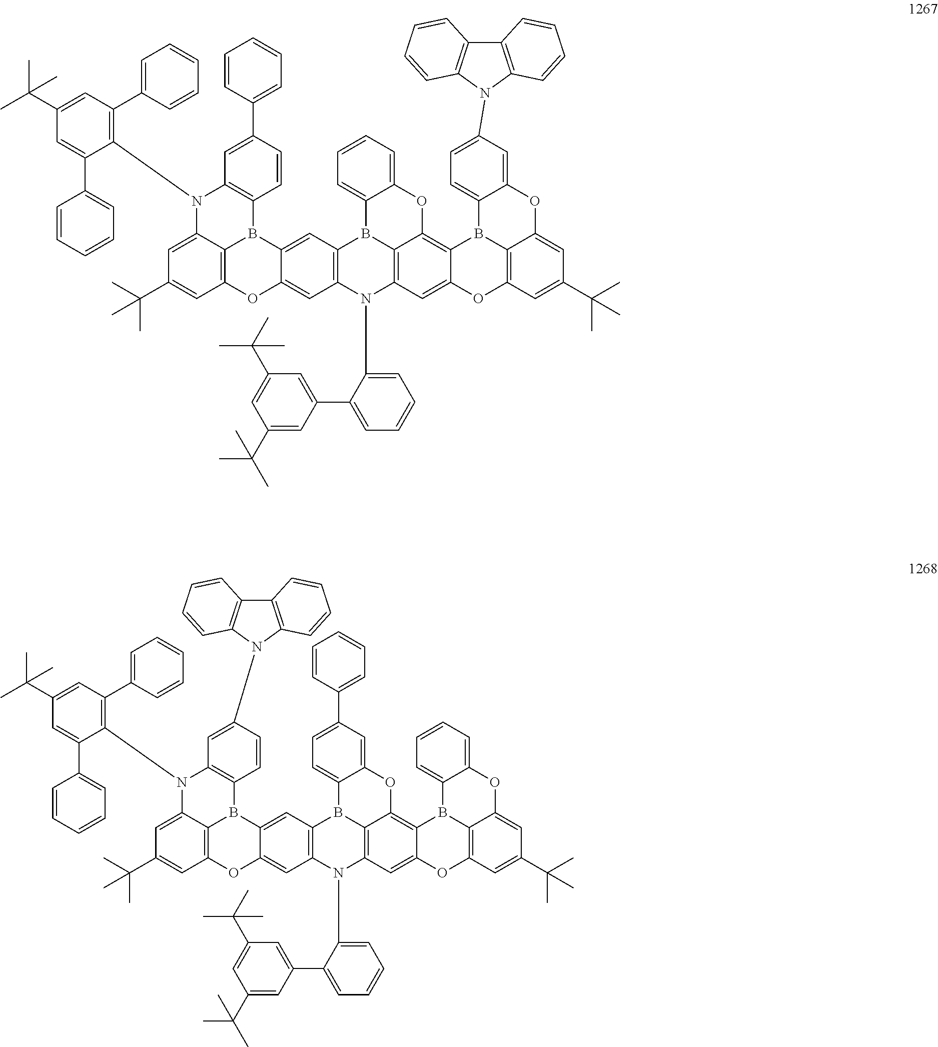 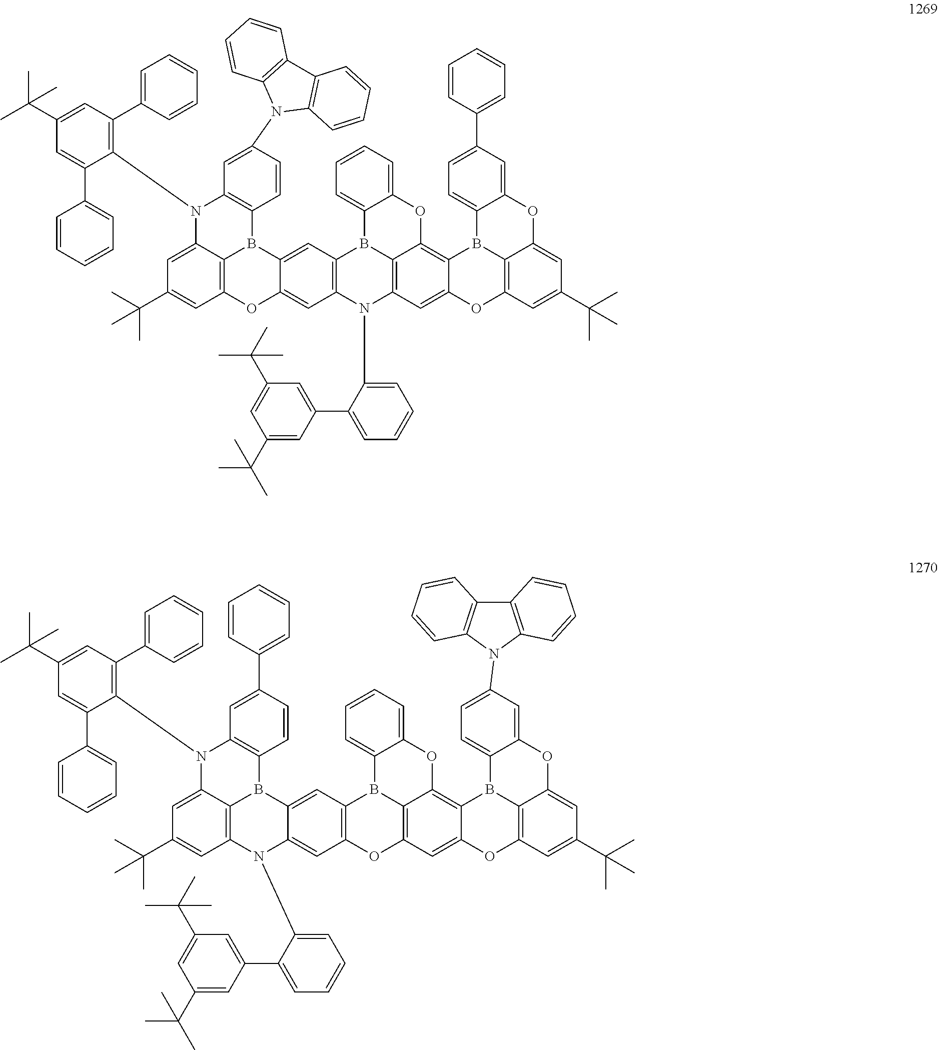 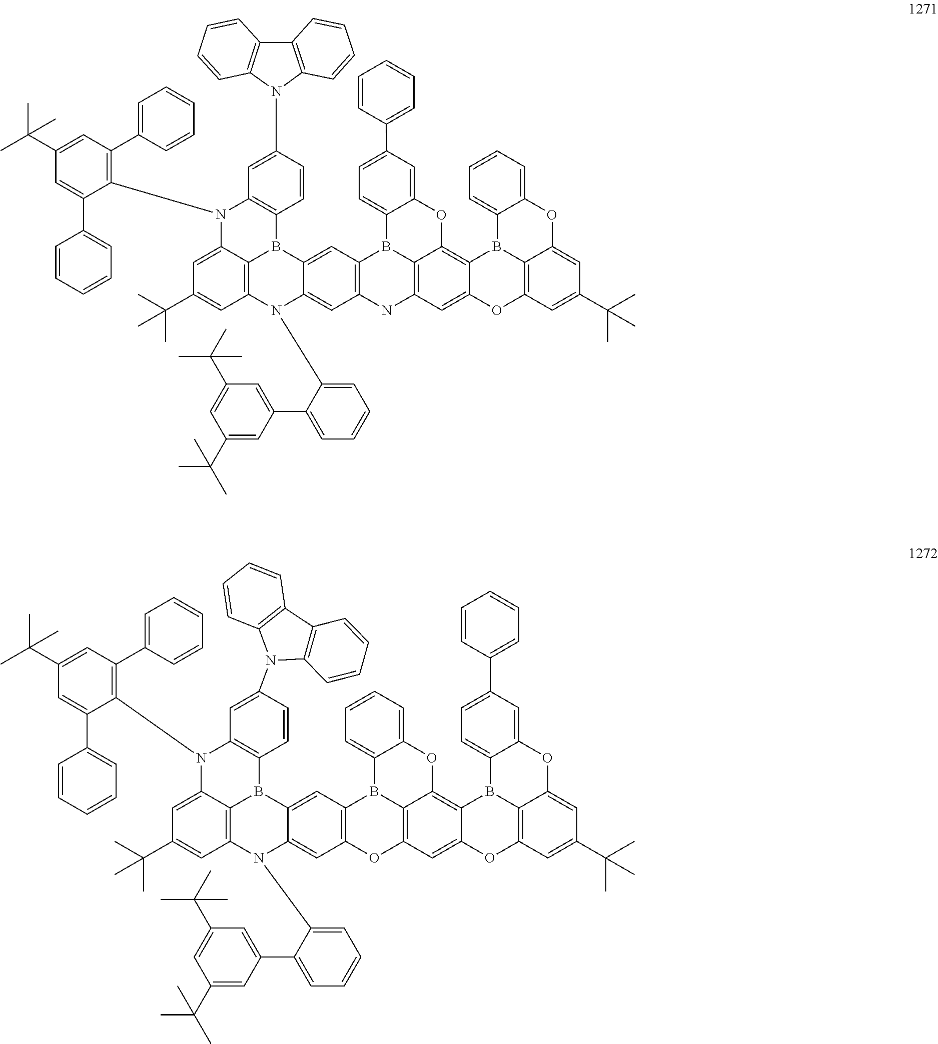 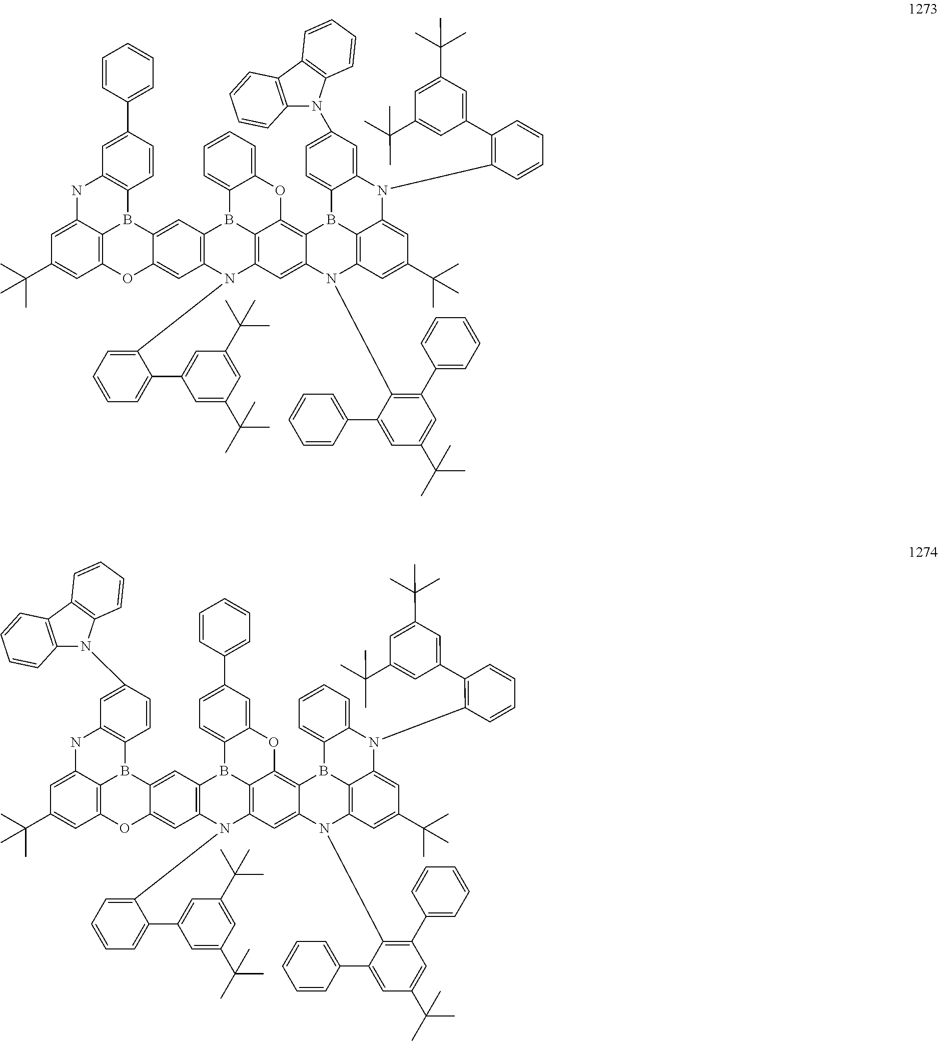 [SMILES: CC(C)(C)c1cc(-c2ccccc2N2c3cc(-n4c5ccccc5c5ccccc54)ccc3B3c4c2cc(C(C)(C)C)cc4N(c2c(-c4ccccc4)cc(C(C)(C)C)cc2-c2ccccc2)c2cc4c5c(c23)Oc2ccccc2B5c2cc3c(cc2N4c2ccccc2-c2cc(C(C)(C)C)cc(C(C)(C)C)c2)Oc2cc(C(C)(C)C)cc4c2B3c2ccc(-c3ccccc3)cc2N4)cc(C(C)(C)C)c1 ; CC(C)(C)c1cc(-c2ccccc2N2c3ccccc3B3c4c2cc(C(C)(C)C)cc4N(c2c(-c4ccccc4)cc(C(C)(C)C)cc2-c2ccccc2)c2cc4c5c(c23)Oc2cc(-c3ccccc3)ccc2B5c2cc3c(cc2N4c2ccccc2-c2cc(C(C)(C)C)cc(C(C)(C)C)c2)Oc2cc(C(C)(C)C)cc4c2B3c2ccc(-n3c5ccccc5c5ccccc53)cc2N4)cc(C(C)(C)C)c1] 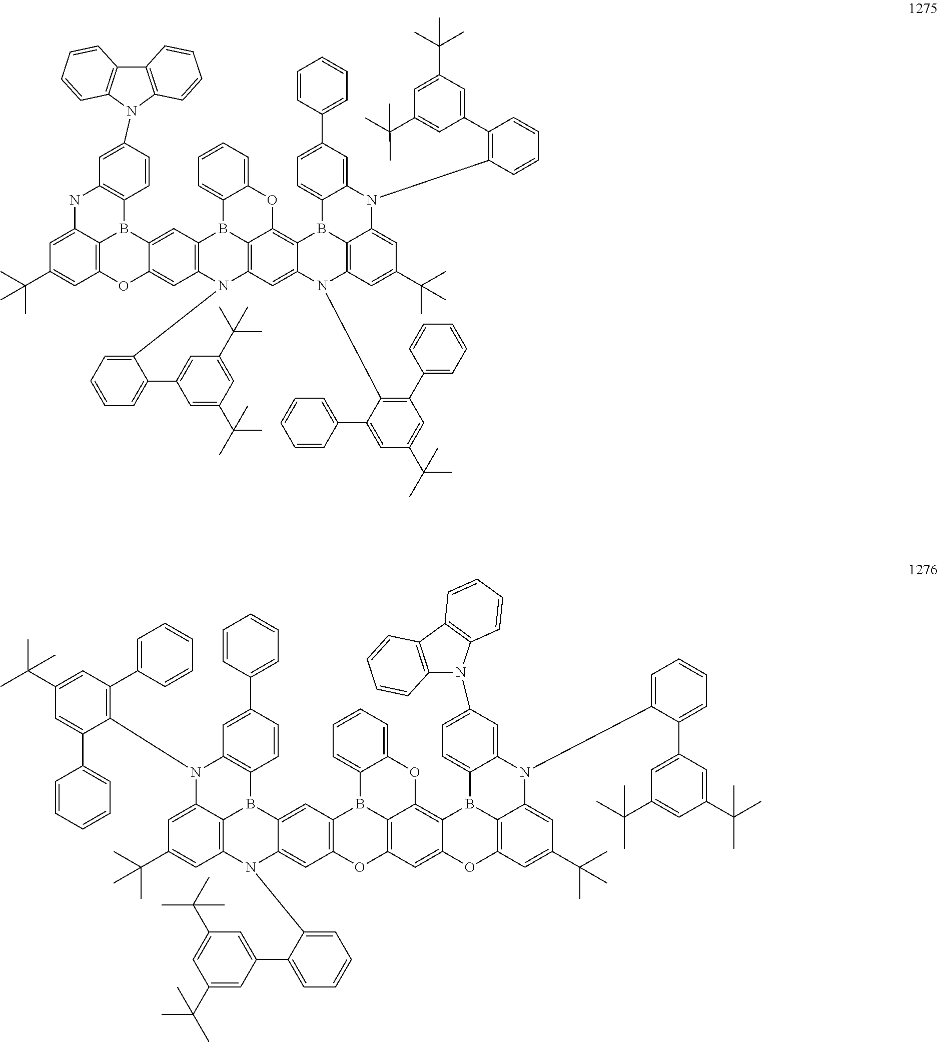 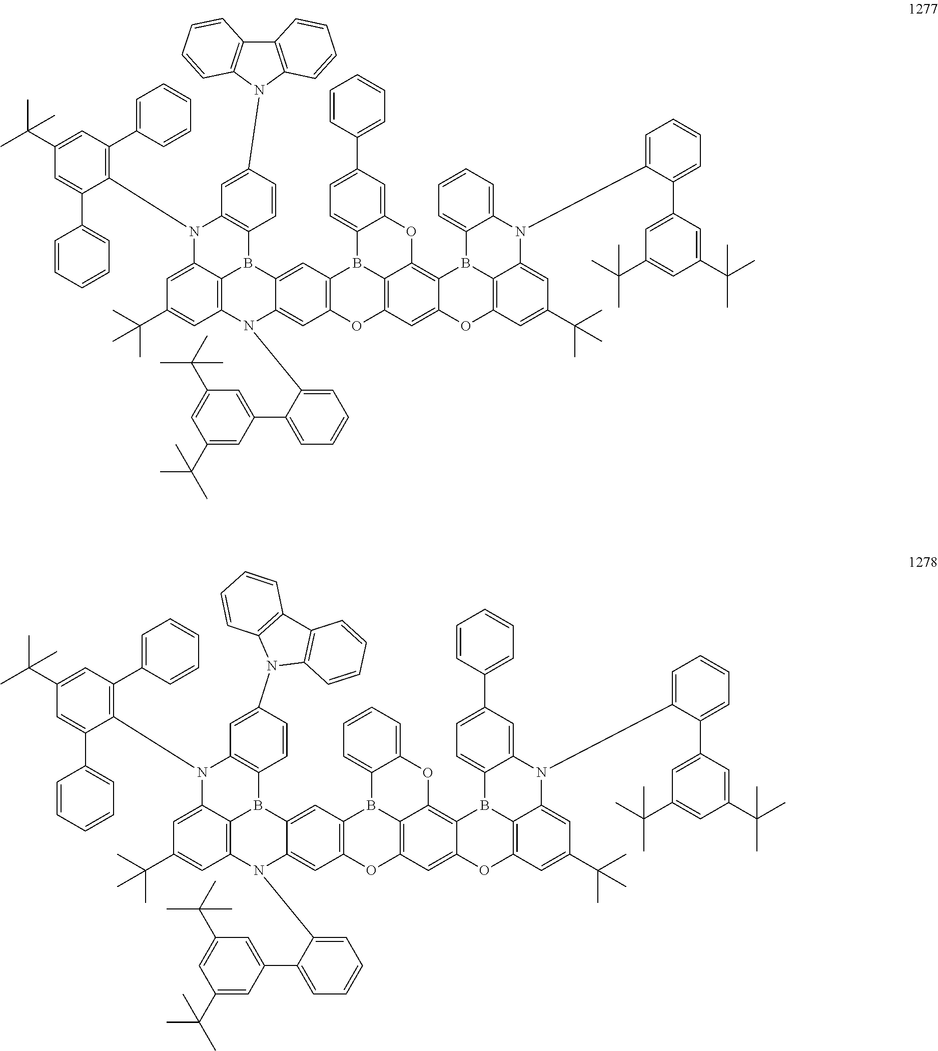 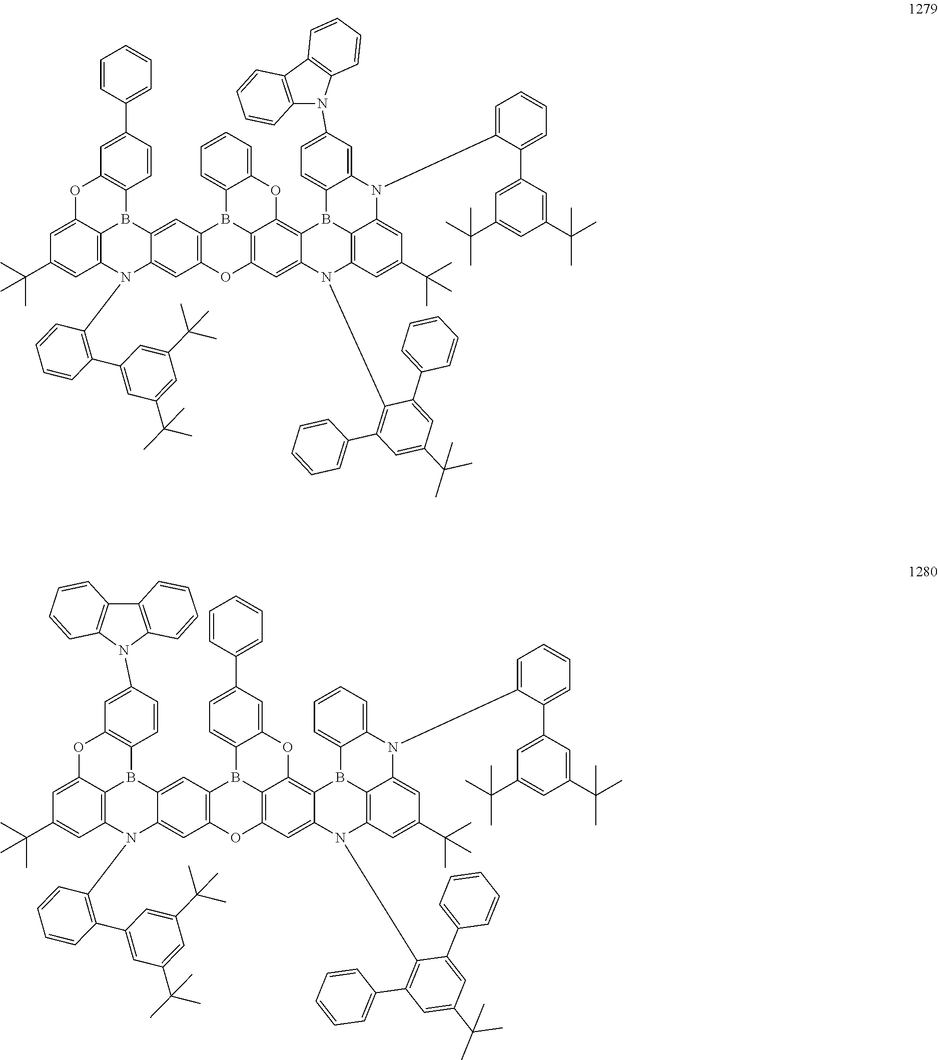 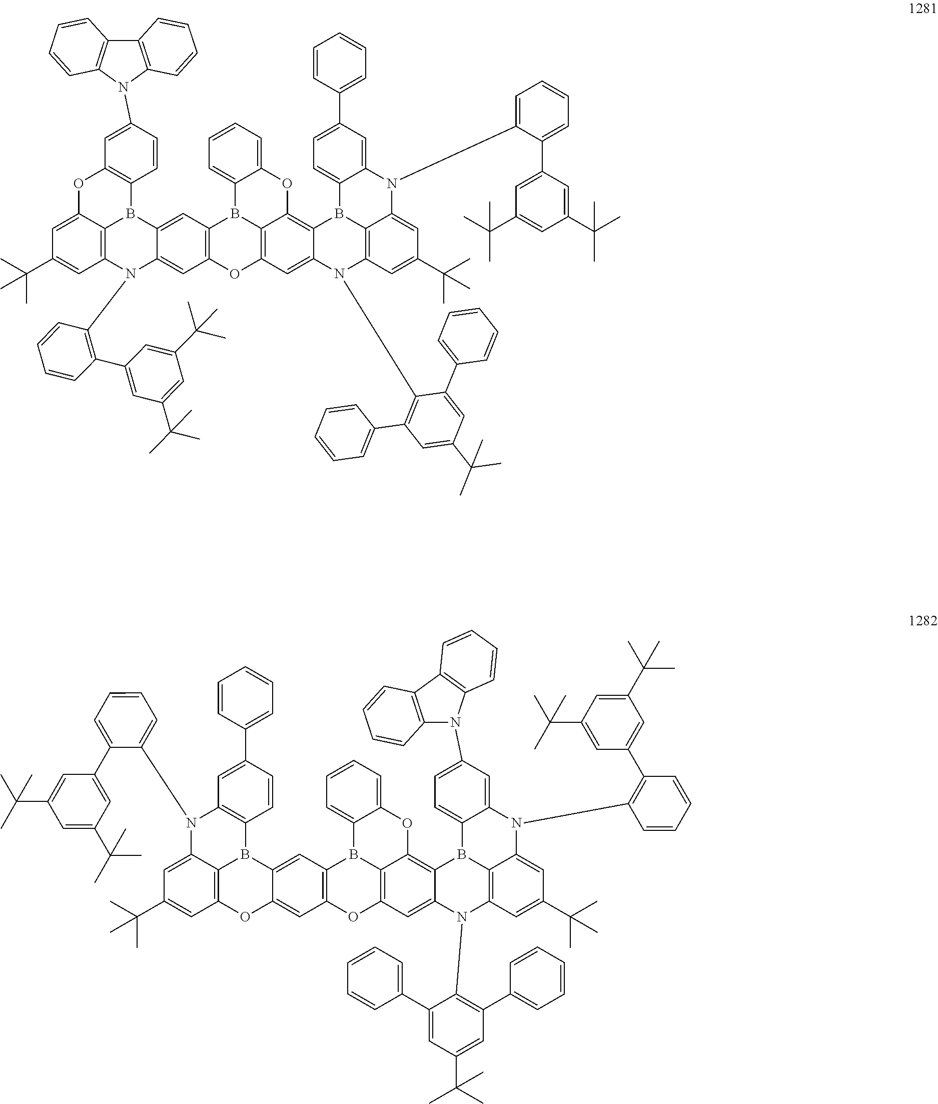 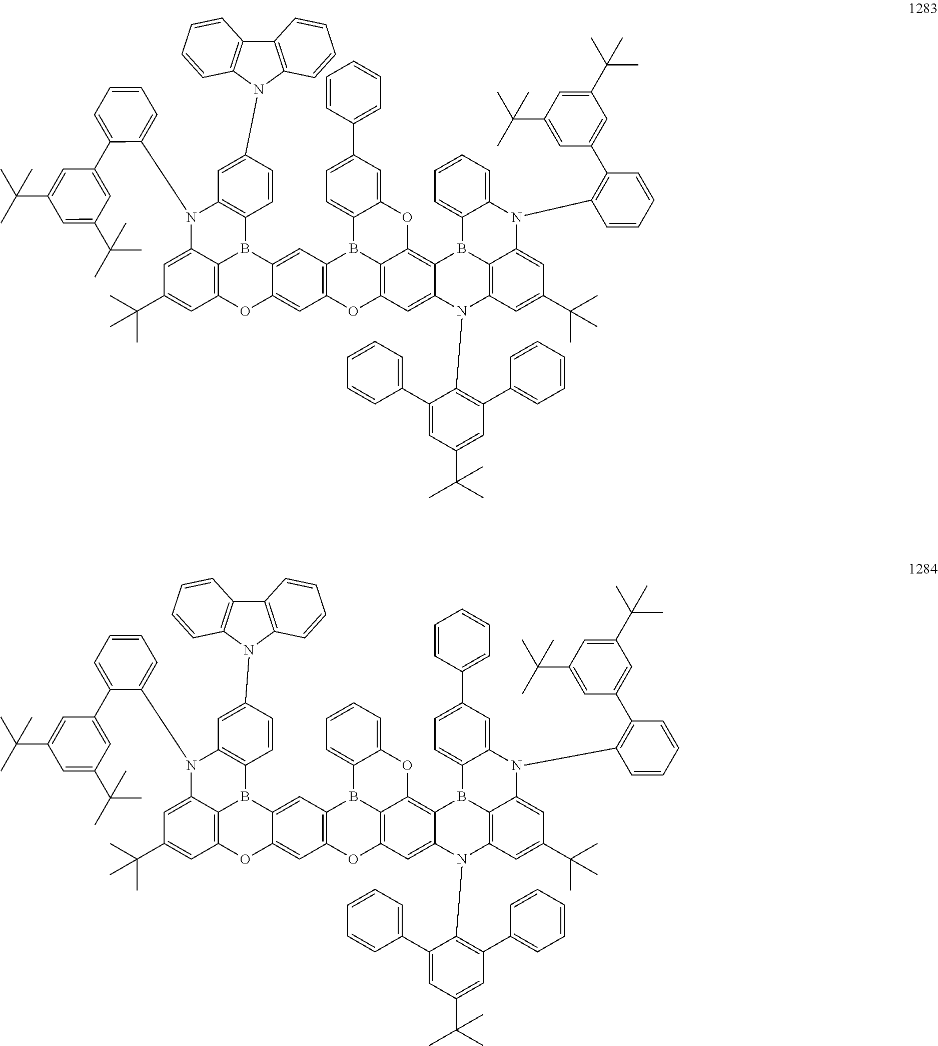 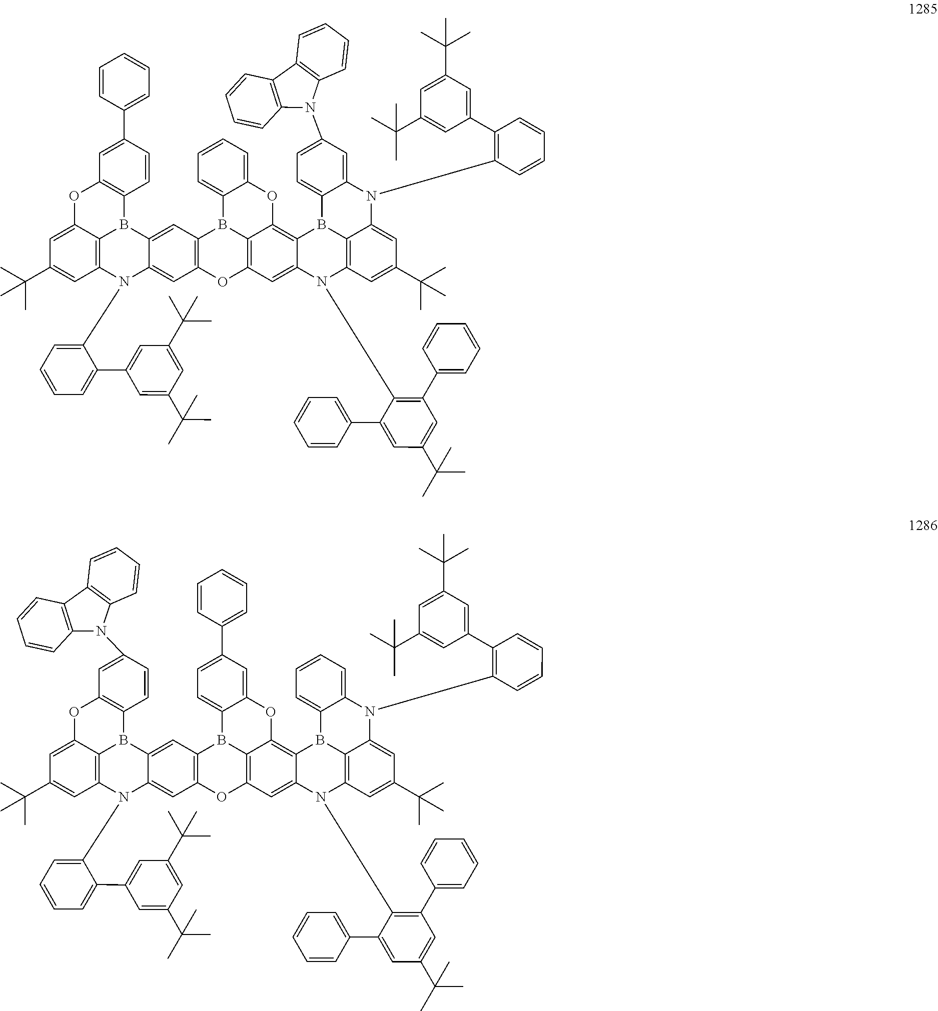 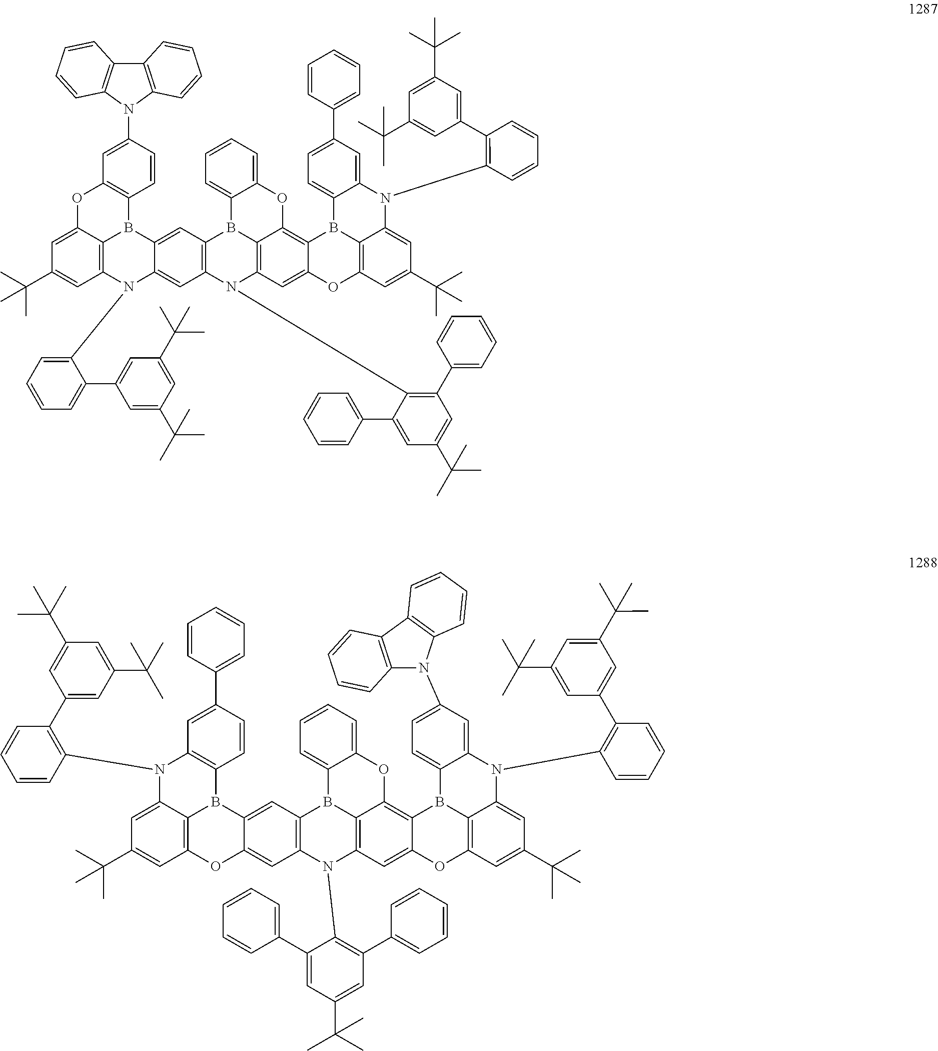 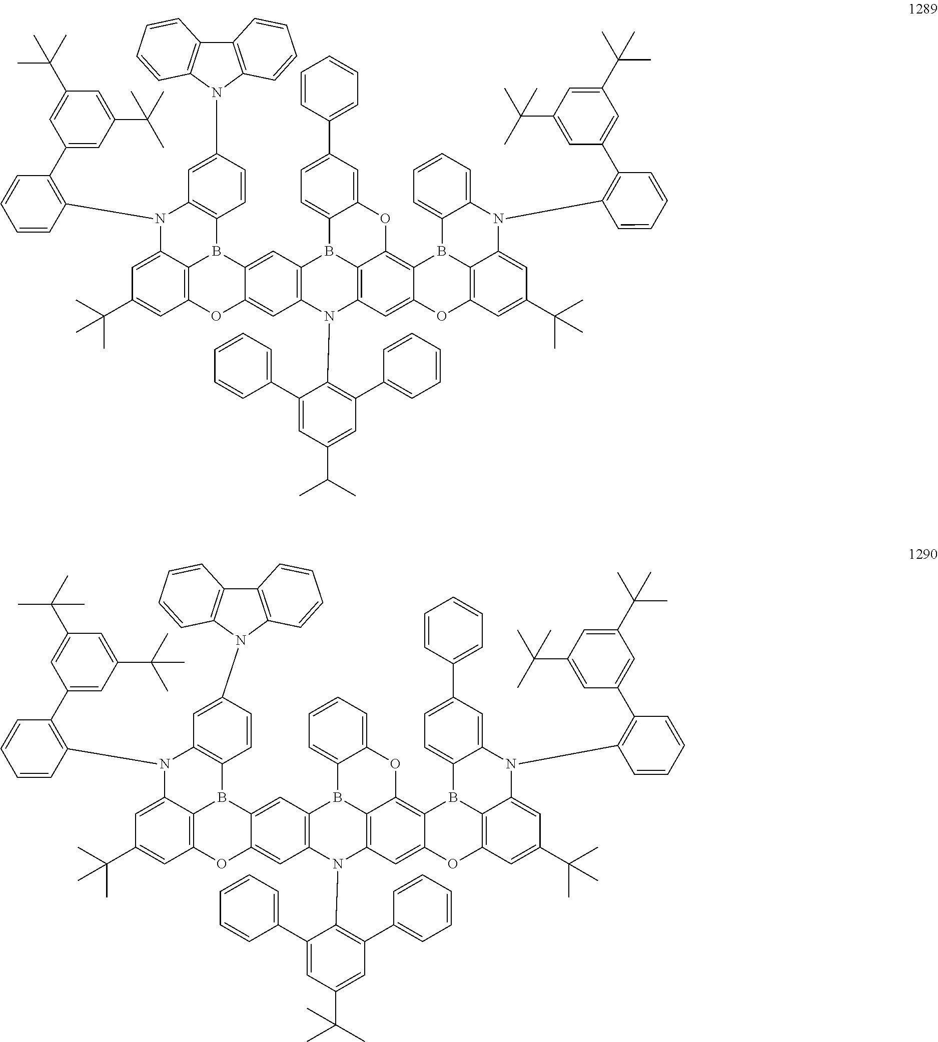 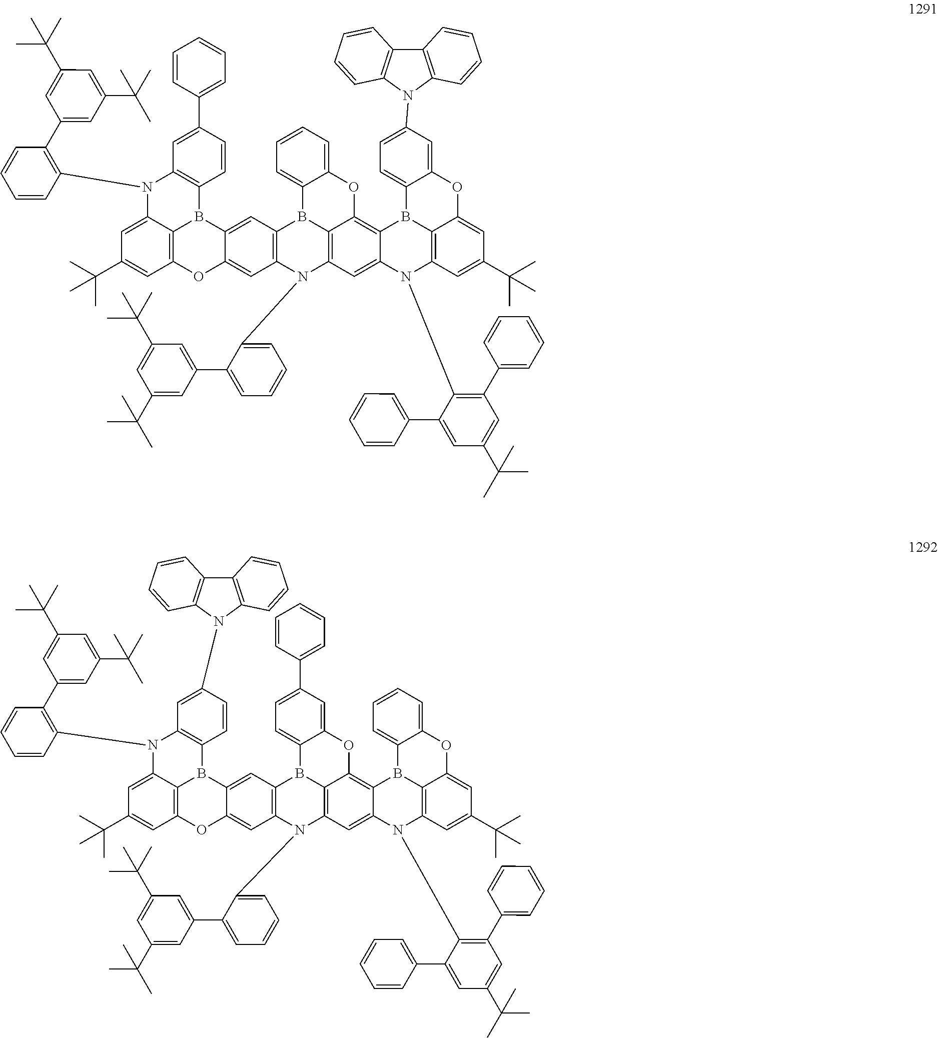 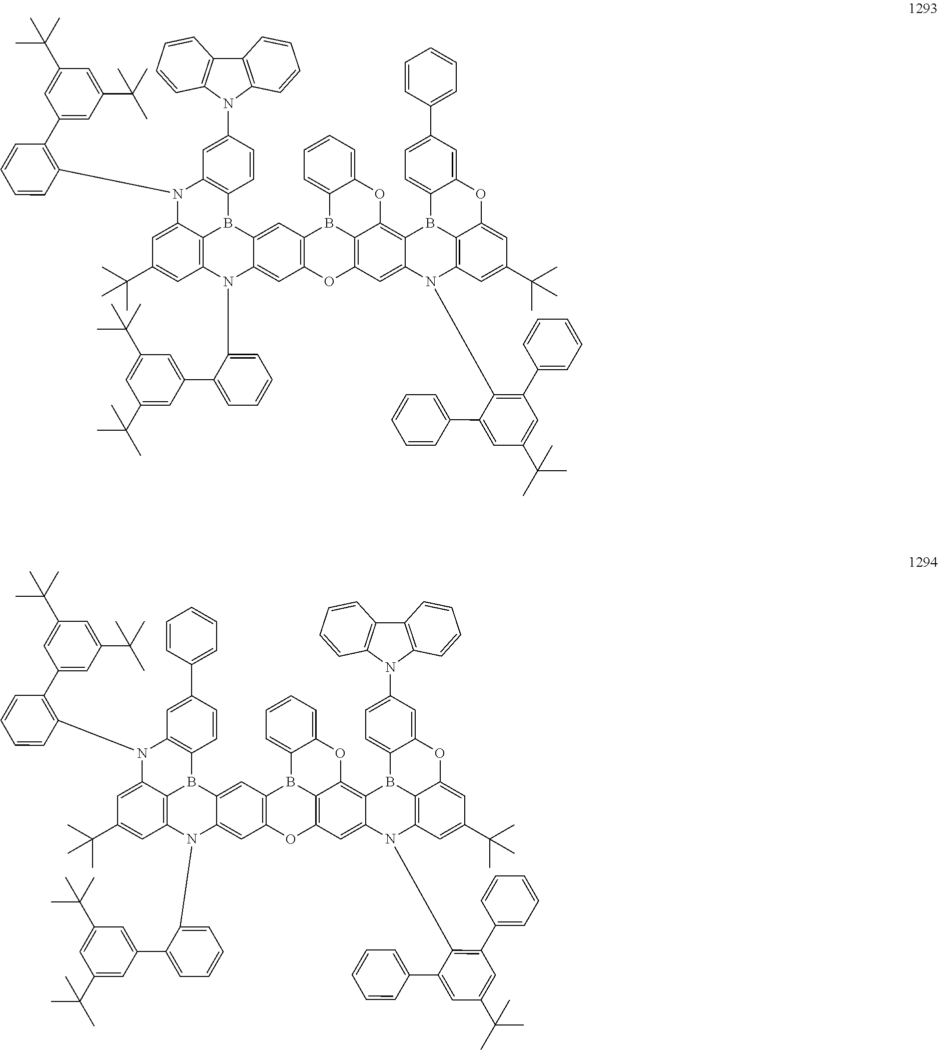 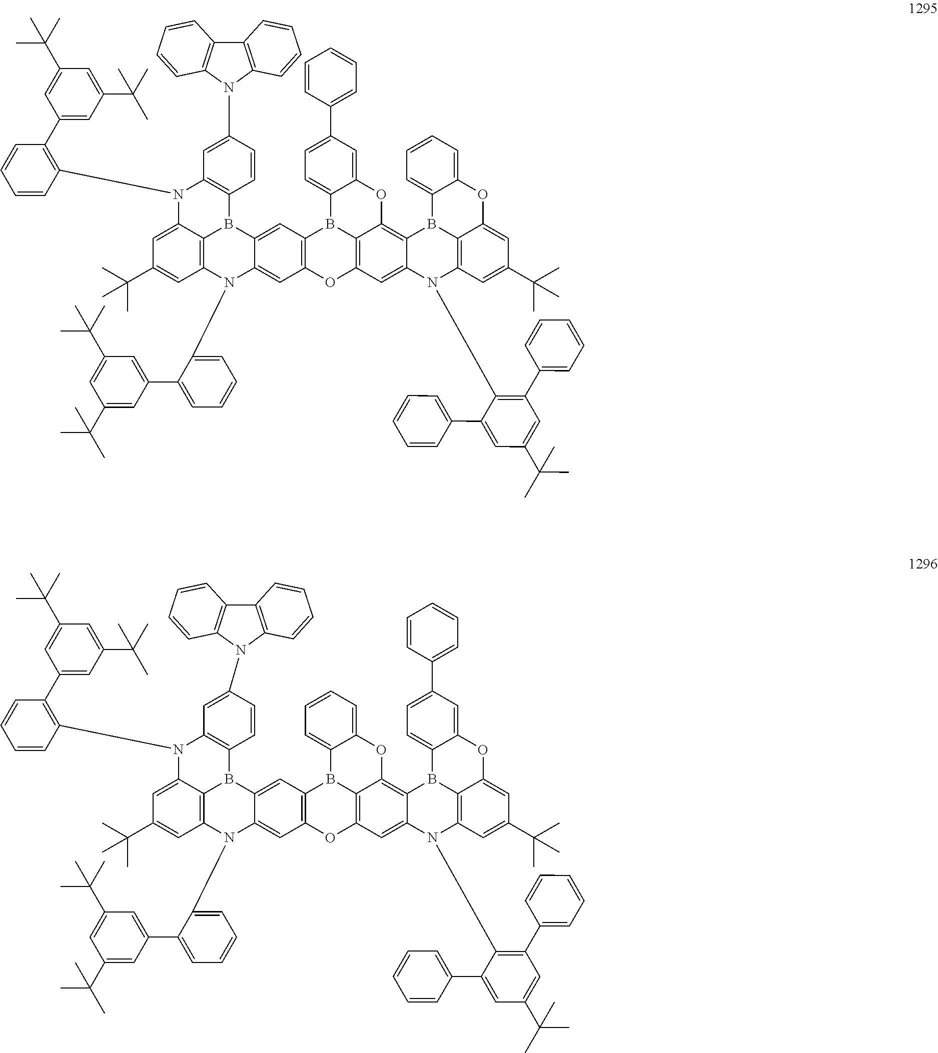 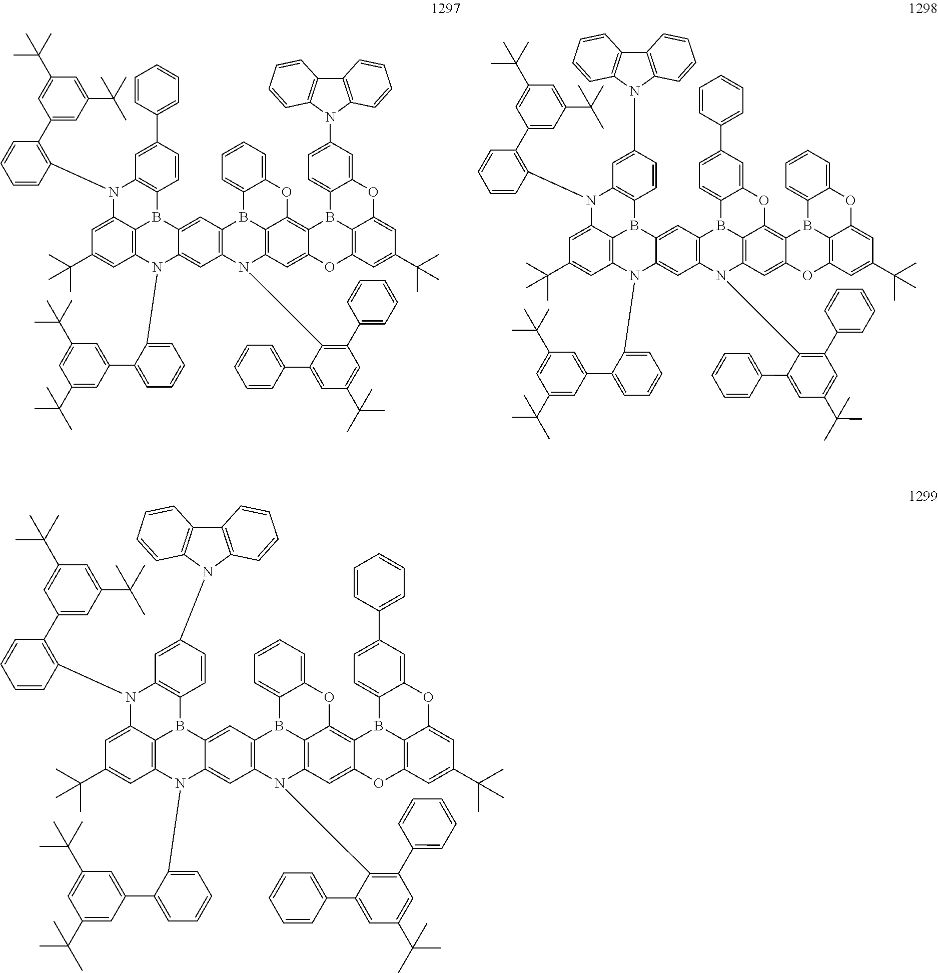 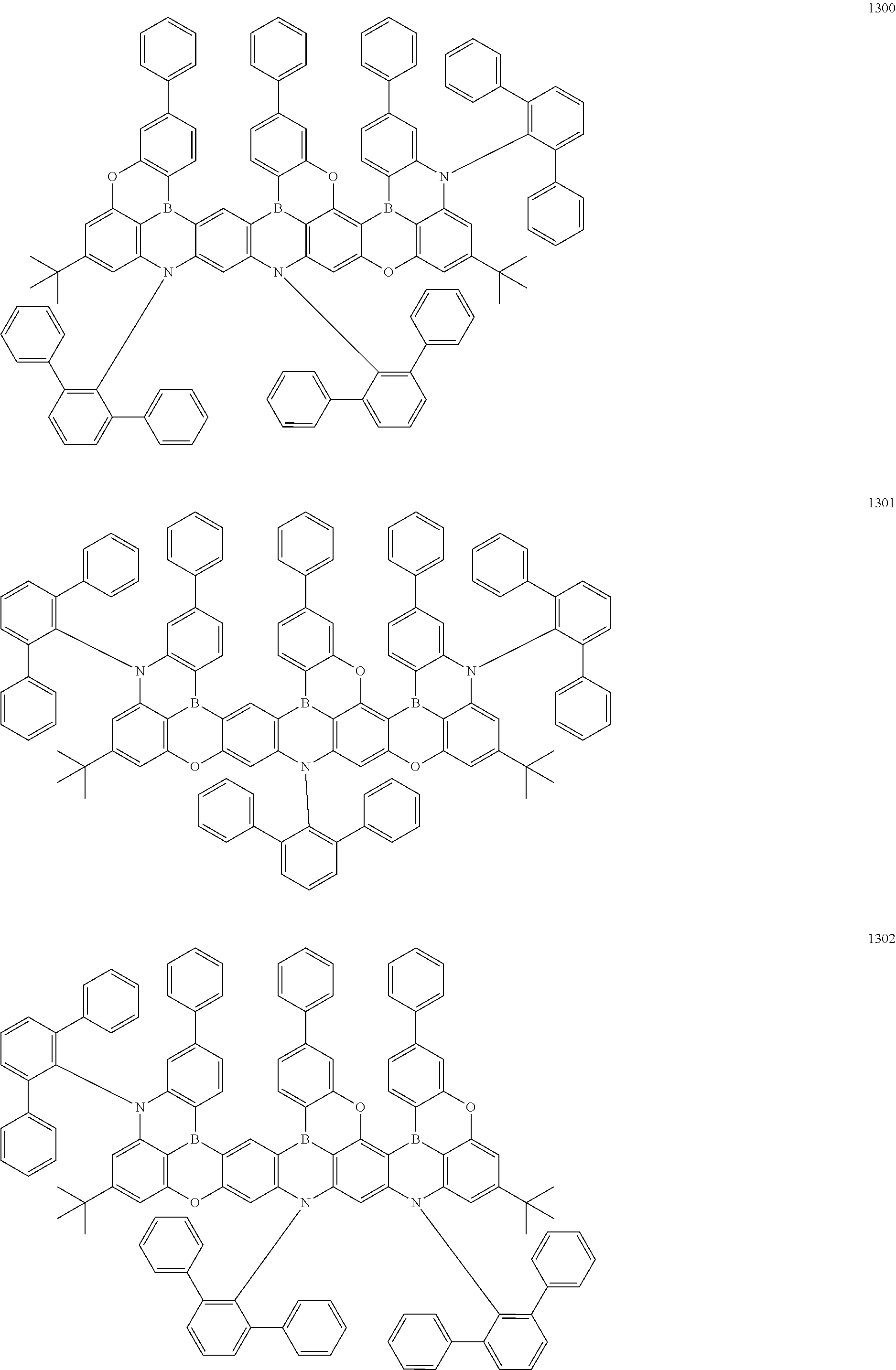 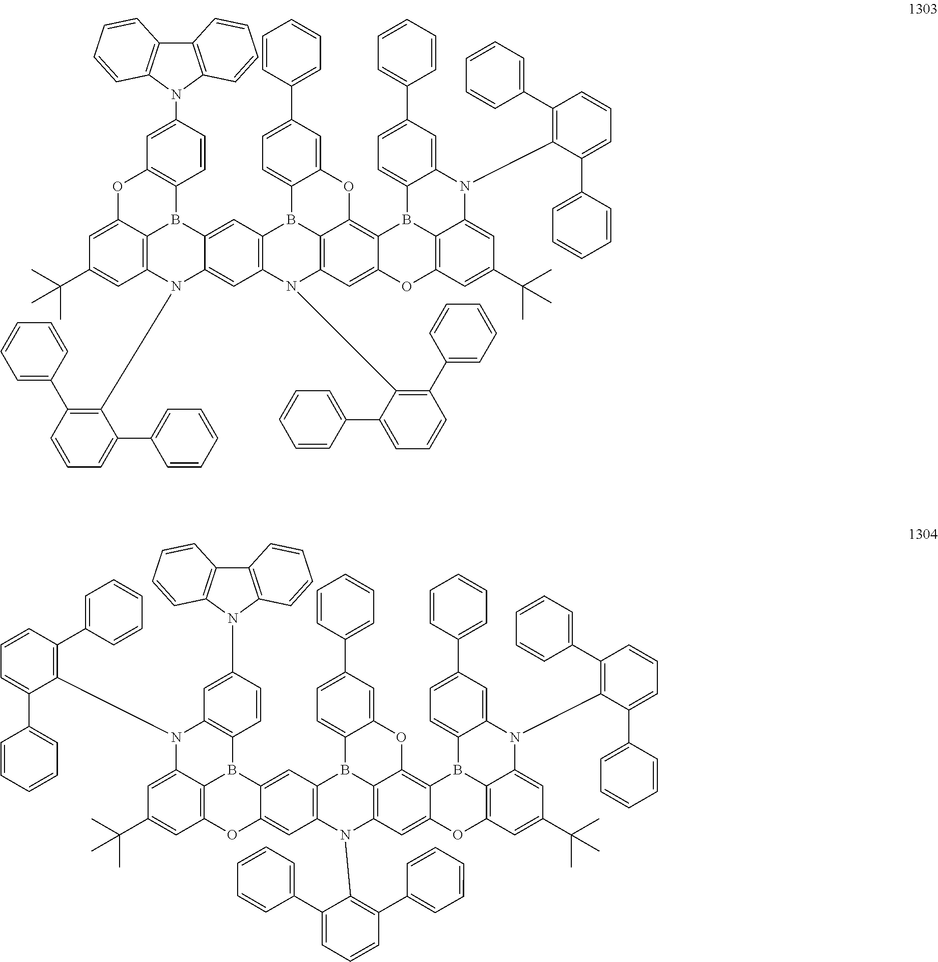 [SMILES: CC(C)(C)c1cc2c3c(c1)N(c1c(-c4ccccc4)cccc1-c1ccccc1)c1cc4c(cc1B3c1ccc(-n3c5ccccc5c5ccccc53)cc1O2)B1c2ccc(-c3ccccc3)cc2Oc2c3c(cc(c21)N4c1c(-c2ccccc2)cccc1-c1ccccc1)Oc1cc(C(C)(C)C)cc2c1B3c1ccc(-c3ccccc3)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc2c(c4c1B3c1ccc(-c3ccccc3)cc1O4)B1c3ccc(-c4ccccc4)cc3N(c3c(-c4ccccc4)cccc3-c3ccccc3)c3cc(C(C)(C)C)cc(c31)O2] 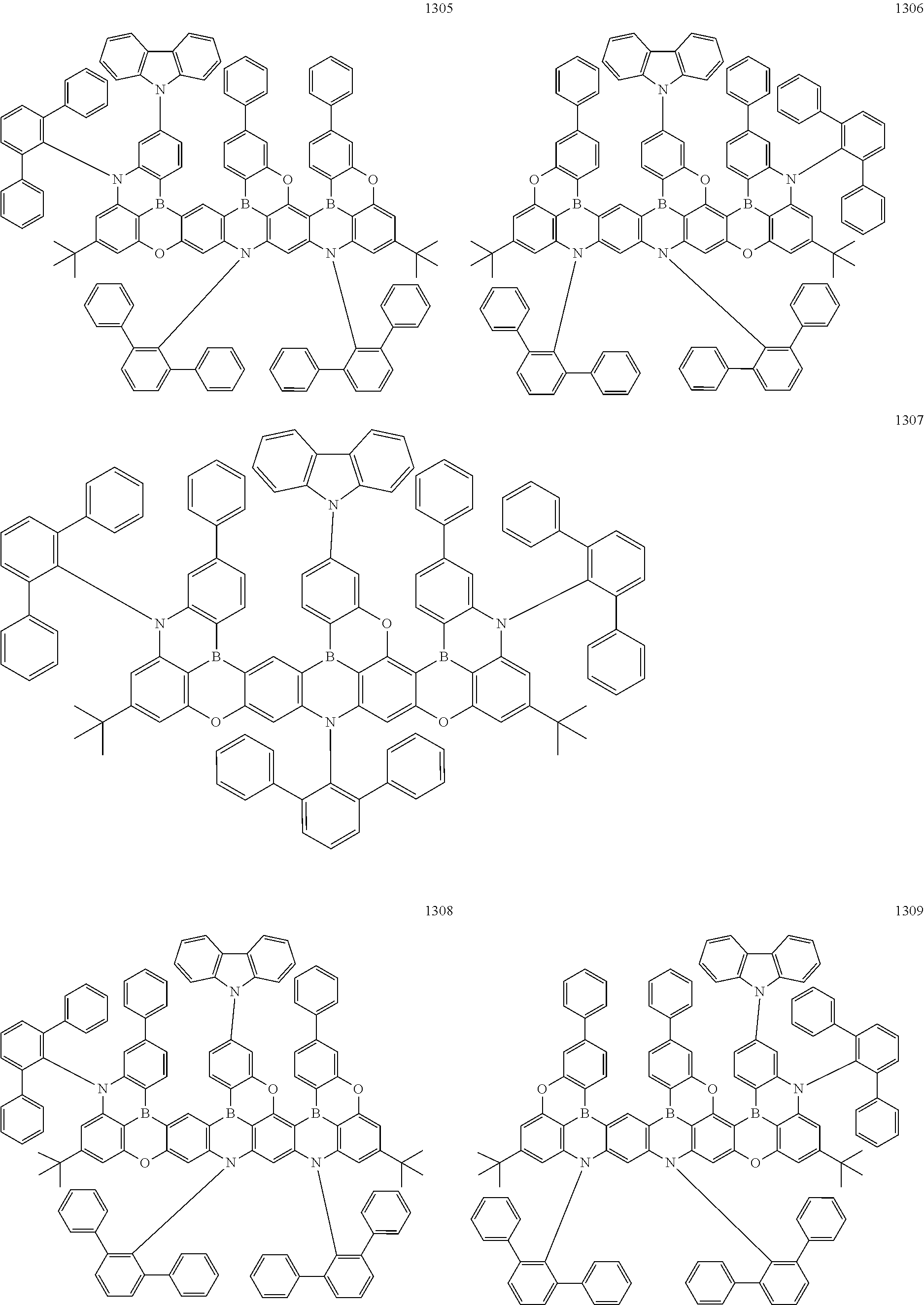 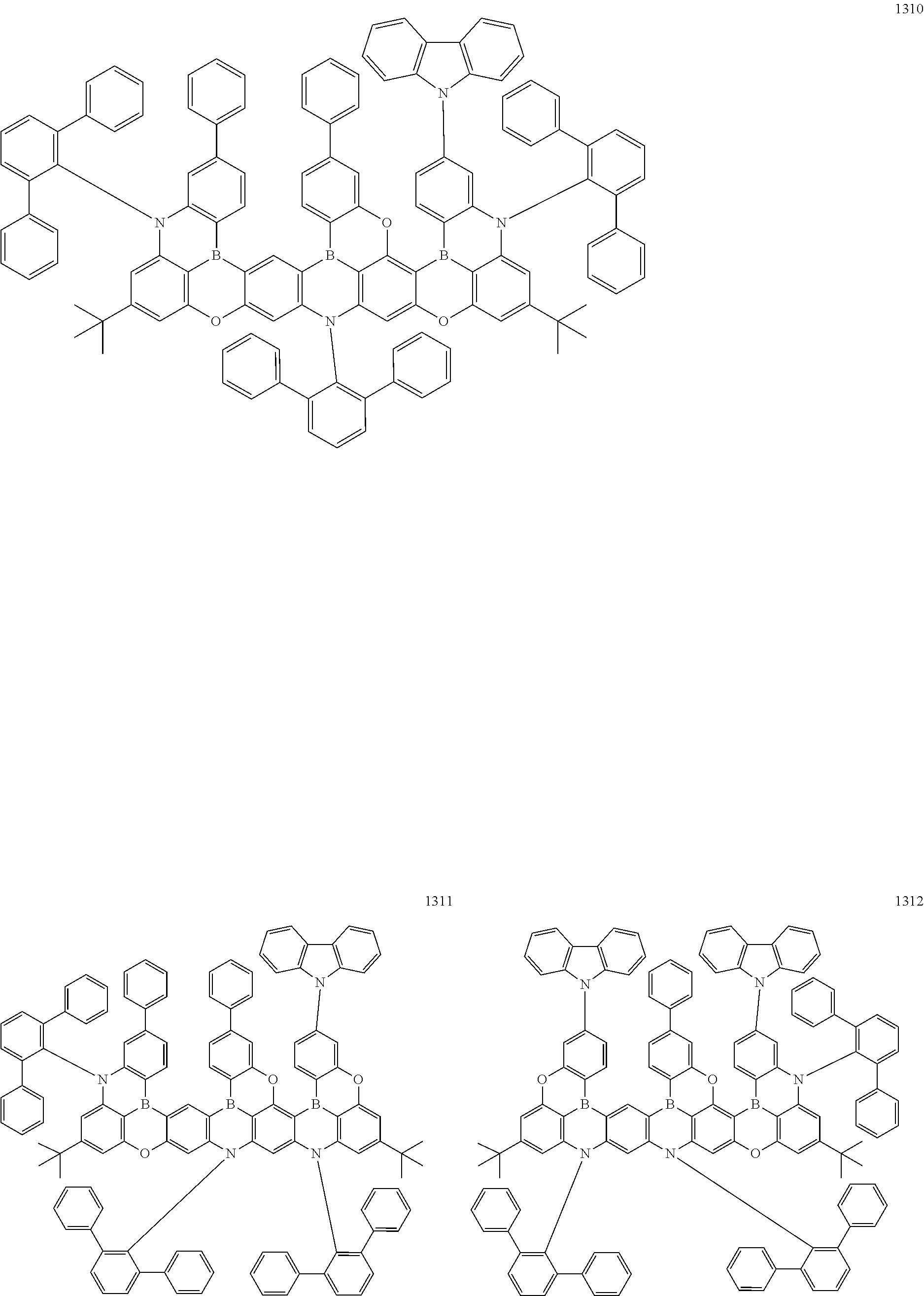
in Compound Group 1, D being deuterium.

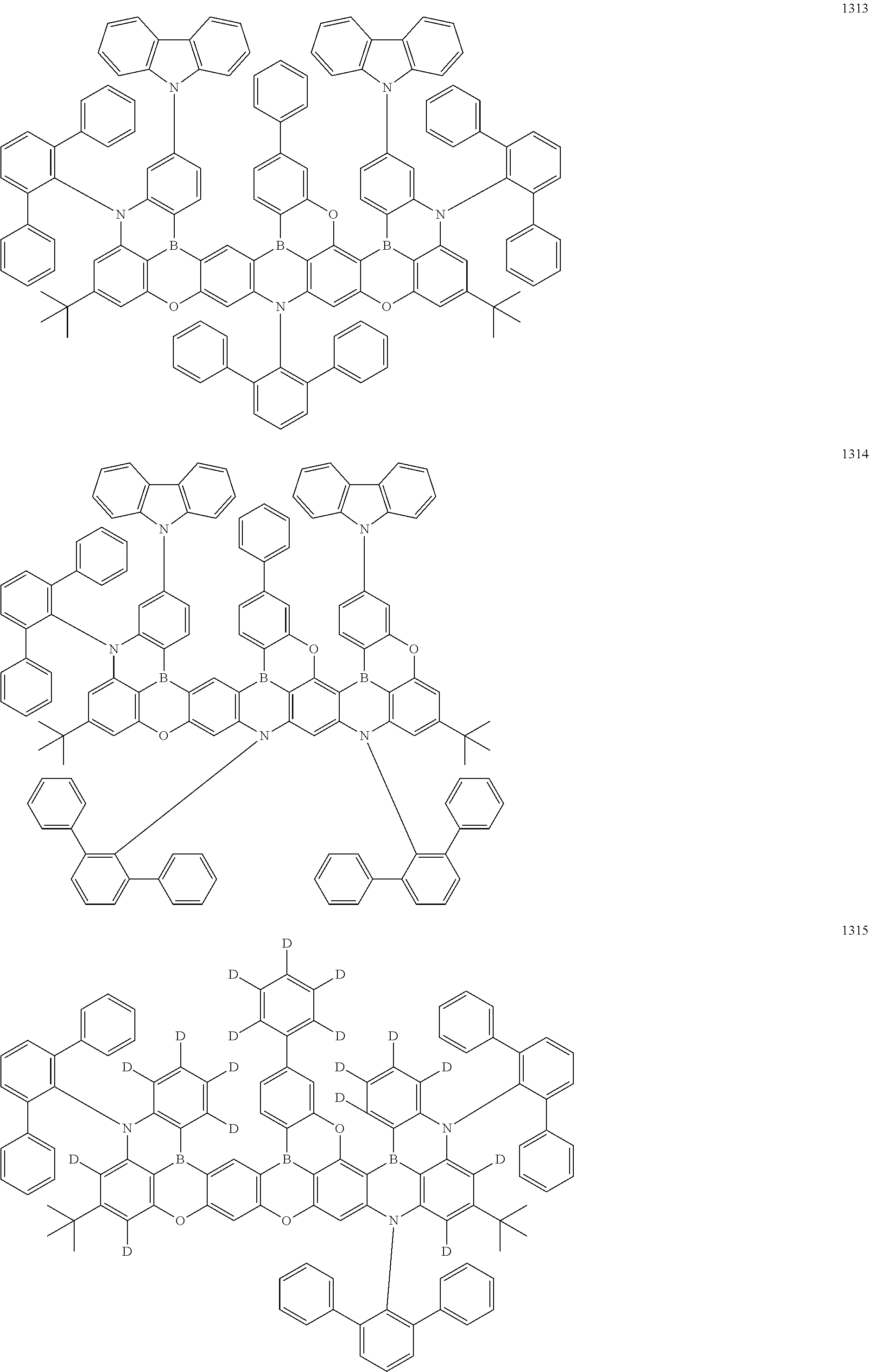

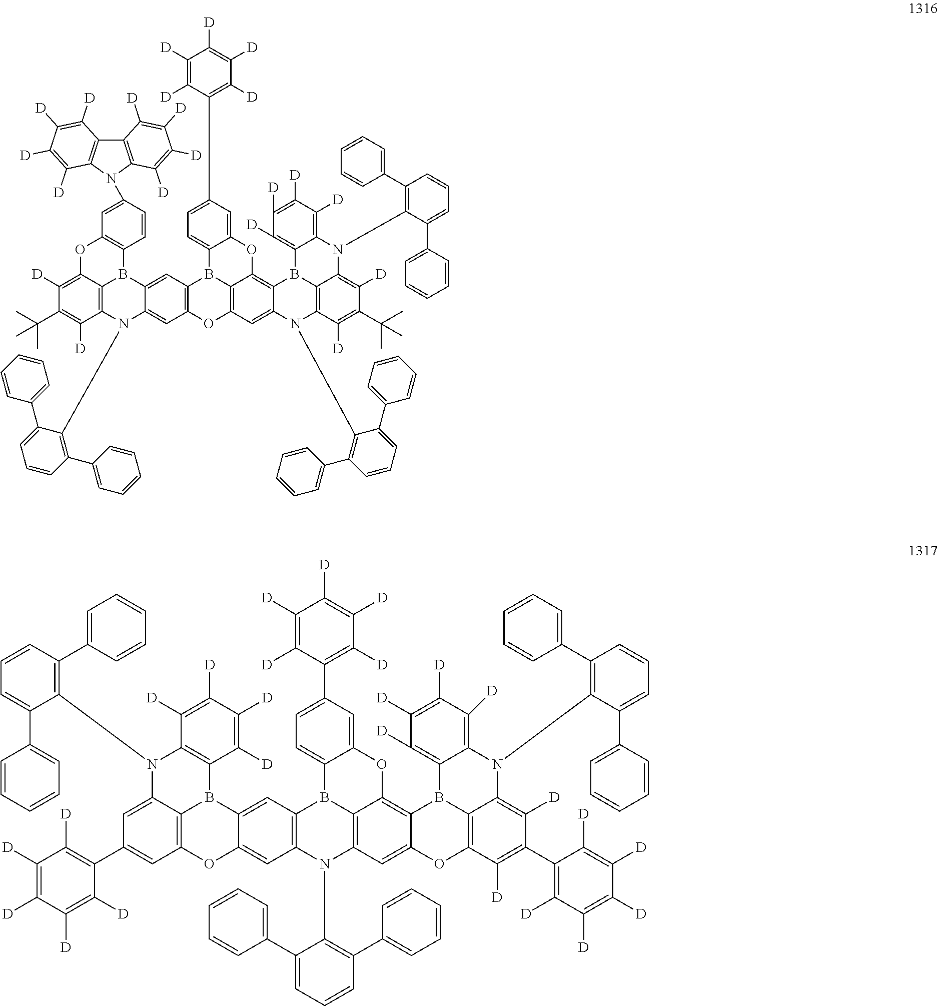

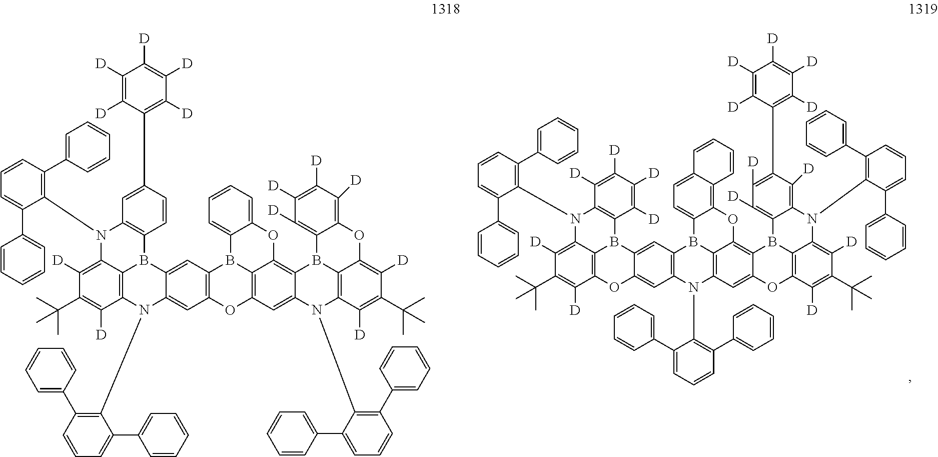

19. An electronic apparatus, comprising a base layer, a circuit layer on the base layer, and a display element layer on the circuit layer and comprising a light emitting element,
wherein the light emitting element comprises a first electrode, a second electrode on the first electrode, and an emission layer between the first electrode and the second electrode and containing a fused polycyclic compound represented by Formula 1: 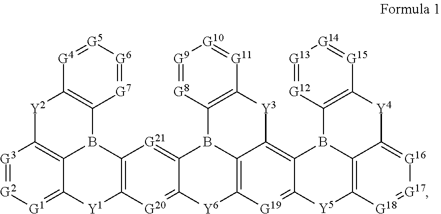
wherein in Formula 1,
Y¹ to Y⁶ are each independently O, S, or NR^{y},
at least one selected from among G¹ to G²¹ is CR^{x1}, and the others are each independently N or CR^{x2},
R^{x1} is deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
R^{x2} and R^{y} are each independently hydrogen, deuterium, a halogen, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 3 to 30 ring-forming carbon atoms, and/or bonded to an adjacent group to form a ring,
when G² is CR^{x1} or CR^{x2}, then R^{x1} and R^{x2} are not substituted or unsubstituted amine groups,
when G¹⁷ is CR^{x1} or CR^{x2}, then R^{x1} and R^{x2} are not substituted or unsubstituted amine groups, and
the fused polycyclic compound comprises a chemical structure in which one or more hydrogens of the fused polycyclic compound are optionally substituted with deuterium.

20. The electronic apparatus of claim 19, further comprising at least one of a processor, a power module, or a memory.
